(19) United States
(12) Patent Application Publication
(10) Pub. No.: US 2025/0268015 A1
(43) Pub. Date: Aug. 21, 2025

(54) COMPOUND AND ORGANIC LIGHT EMITTING DEVICE COMPRISING SAME

(71) Applicant: LG CHEM, LTD., Seoul (KR)

(72) Inventors: Moung Gon Kim, Daejeon (KR); Woochul Lee, Daejeon (KR); Sujeong Geum, Daejeon (KR); Kyunghee Kim, Daejeon (KR); Hye Min Cho, Daejeon (KR); Hojung Lee, Daejeon (KR)

(21) Appl. No.: 18/022,736

(22) PCT Filed: Dec. 23, 2021
(86) PCT No.: PCT/KR2021/019747

§ 371 Date: Feb. 22, 2023

(30) Foreign Application Priority Data
Dec. 24, 2020 (KR) 10-2020-0183776
Jun. 17, 2021 (KR) 10-2021-0078639

(51) Int. Cl. H10K 50/12; H10K 85/60; H10K 101/00

(52) U.S. Cl. CPC H10K 50/12; H10K 85/615; H10K 85/633; H10K 85/636; H10K 85/654; H10K 85/6572; H10K 85/658; H10K 2101/90

(57) ABSTRACT

A compound of Chemical Formula 1 and an organic light emitting device including the same are provided. The compound is used as a material of an organic material layer of the organic light emitting device, and provides high color purity, high efficiency and enhanced lifetime properties.

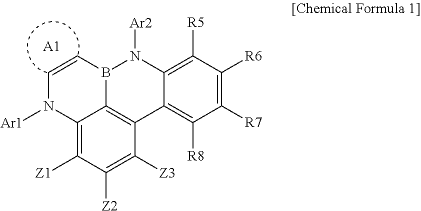

### CROSS-REFERENCE TO RELATED APPLICATION

This application is a National Stage Application of International Application No. PCT/KR2021/019747 filed on Dec. 23, 2021, which claims priority to Korean Patent Application No. 10-2020-0183776 filed on Dec. 24, 2020, and Korean Patent Application No. 10-2021-0078639 filed on Jun. 17, 2021, the disclosures of which are incorporated herein by reference in their entireties.

### FIELD OF DISCLOSURE

The present specification relates to a compound, and an organic light emitting device including the same.

### BACKGROUND

An organic light emission phenomenon generally refers to a phenomenon converting electrical energy to light energy using an organic material. An organic light emitting device using an organic light emission phenomenon normally has a structure including an anode, a cathode, and an organic material layer therebetween.

Herein, the organic material layer is often formed in a multilayer structure formed with different materials in order to increase efficiency and stability of the organic light emitting device, and for example, may be formed with a hole injection layer, a hole transfer layer, a light emitting layer, an electron transfer layer, an electron injection layer and the like. When a voltage is applied between the two electrodes in such an organic light emitting device structure, holes and electrons are injected to the organic material layer from the anode and the cathode, respectively, and when the injected holes and electrons meet, excitons are formed, and light emits when these excitons fall back to the ground state.

Development of new materials for such an organic light emitting device has been continuously required. Among these, a blue organic light emitting device essentially needs to have high color purity and long lifetime properties, however, technologies to obtain both at the same time is insufficient due to instability caused by high energy of a blue material. Recently, a thermally active delayed fluorescent material having a core structure including boron has been newly developed and received attention with its high efficiency and color purity, however, the material has disadvantages of having a short lifetime due to high triplet energy and slow reverse intersystem crossing rate. Accordingly, development of a blue organic light emitting material achieving high color purity and long lifetime properties at the same time has been required.

### SUMMARY

The present specification is directed to providing a compound, and an organic light emitting device including the same.

One embodiment of the present specification provides a compound represented by the following Chemical Formula 1.

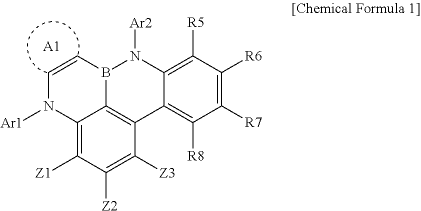

In Chemical Formula 1,
A1 is one selected from the group consisting of a substituted or unsubstituted aromatic hydrocarbon ring; a substituted or unsubstituted aliphatic hydrocarbon ring; a substituted or unsubstituted heteroring; and a fused ring thereof,
R5 to R8 are the same as or different from each other, and each independently hydrogen; deuterium; a halogen group; a cyano group; a substituted or unsubstituted alkyl group; a substituted or unsubstituted cycloalkyl group; a substituted or unsubstituted alkoxy group; a substituted or unsubstituted arylalkyl group; a substituted or unsubstituted aryloxy group; a substituted or unsubstituted silyl group; a substituted or unsubstituted amine group; a substituted or unsubstituted aryl group; a substituted or unsubstituted fused ring group of an aromatic hydrocarbon ring and an aliphatic hydrocarbon ring; or a substituted or unsubstituted heterocyclic group, or adjacent groups among R5 to R8 bond to each other to form a substituted or unsubstituted ring,
Ar1 is a substituted or unsubstituted cycloalkyl group; a substituted or unsubstituted aryl group; a substituted or unsubstituted fused ring group of an aromatic hydrocarbon ring and an aliphatic hydrocarbon ring; or a substituted or unsubstituted heterocyclic group, or bonds to A1 to form one selected from the group consisting of an aromatic heteroring, an aliphatic heteroring and a fused ring thereof which is substituted or unsubstituted and including one or more selected from N, S, O and Si,
Ar2 is a substituted or unsubstituted cycloalkyl group; a substituted or unsubstituted aryl group; a substituted or unsubstituted fused ring group of an aromatic hydrocarbon ring and an aliphatic hydrocarbon ring; or a substituted or unsubstituted heterocyclic group, or bonds to R5 to form one selected from the group consisting of an aromatic heteroring, an aliphatic heteroring and a fused ring thereof which is substituted or unsubstituted and including one or more selected from N, S, O and Si,
when Ar2 and R5 form a benzoxazine ring, the benzoxazine ring is an unsubstituted benzoxazine ring,
at least one of Z1 to Z3 is deuterium; a halogen group; a cyano group; a substituted or unsubstituted alkyl group; a substituted or unsubstituted cycloalkyl group; a substituted or unsubstituted alkoxy group; a substituted or unsubstituted arylalkyl group; a substituted or unsubstituted aryloxy group; a substituted or unsubstituted silyl group; a substituted or unsubstituted amine group; a substituted or unsubstituted aryl group; a substituted or unsubstituted fused ring group of an aromatic hydrocarbon ring and an aliphatic hydrocarbon ring; or a substituted or unsubstituted heterocyclic group, or adjacent groups among Z1 to Z3 bond to each other to form a substituted or unsubstituted ring, and the rest are hydrogen, and
when Ar1 is a phenyl group, and A1 is substituted or unsubstituted benzene, and R6 to R8 are hydrogen, and adjacent groups among Z1 to Z3 do not bond to each other to form a substituted or unsubstituted ring, and Ar2 and R5 form an indole group at the same time, the indole group is a substituted indole group.

Another embodiment of the present specification provides an organic light emitting device including a first electrode; a second electrode; and an organic material layer comprising one or more layers provided between the first electrode and the second electrode, wherein one or more layers of the organic material layer include the compound.

A compound according to one embodiment of the present specification can be used as a material of an organic material layer of an organic light emitting device, and by using the same, high color purity, high efficiency and/or enhanced lifetime properties are obtained in the organic light emitting device.

### BRIEF DESCRIPTION OF DRAWINGS

FIG. 1 and FIG. 2 each illustrate an organic light emitting device according to one embodiment of the present specification.

FIG. 3 is a diagram illustrating a molecular model obtained by a simulation of a Dopant B and BH system of Example 2-1 of the present specification.

FIG. 4 is a diagram illustrating a molecular model obtained by a simulation of a BD1 and BH system of Comparative Example 2-1 of the present specification.

FIG. 5 is a diagram illustrating a molecular model obtained by a simulation of a BD2 and BH system of Comparative Example 2-2 of the present specification.

FIG. 6 is a diagram showing orbital distribution of HOMO and LUMO of BD1.

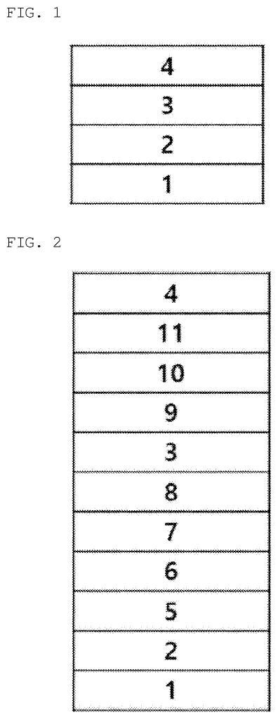

### DESCRIPTION OF REFERENCE NUMERAL

1: Substrate
2: First Electrode
3: Light Emitting Layer
4: Second Electrode
5: First Hole Injection Layer
6: Second Hole Injection Layer
7: Hole Transfer Layer
8: Electron Blocking Layer
9: First Electron Transfer Layer
10: Second Electron Transfer Layer
11: Electron Injection Layer

### DETAILED DESCRIPTION

Hereinafter, the present specification will be described in more detail.

One embodiment of the present specification relates to a compound represented by Chemical Formula 1.

An existing organic light emitting device using a boron-based compound has high efficiency compared to an organic light emitting device using a pyrene-based compound, but has a disadvantage of short lifetime. However, the compound represented by Chemical Formula 1 has a narrow full width at half maximum, and an organic light emitting device including the same has advantages of increasing efficiency and lifetime. A narrow full width at half maximum is maintained by the hexagonal ring of boron and amine, and by filling insufficient electrons of the boron through a direct bond of boron and amine on the opposite side, stability of the core in an unstable polaron state increases, which increases a lifetime, and by facilitating a transition of the polaron into an exciton state, an organic light emitting device including the same has increased efficiency.

Throughout the specification of the present application, a term “combination thereof” included in a Markush-type expression means a mixture or a combination of one or more selected from the group consisting of constituents described in the Markush-type expression, and means including one or more selected from the group consisting of the constituents.

Examples of substituents in the present specification are described below, however, the substituents are not limited thereto.

In the present specification,

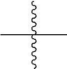

means a linked site.

The term “substitution” means a hydrogen atom bonding to a carbon atom of a compound being changed to another substituent, and the position of substitution is not limited as long as it is a position at which the hydrogen atom is substituted, that is, a position at which a substituent is capable of substituting, and when two or more substituents substitute, the two or more substituents may be the same as or different from each other.

In the present specification, a term “substituted or unsubstituted” means being substituted with one or more substituents selected from the group consisting of deuterium; a halogen group; a cyano group; an alkyl group; a cycloalkyl group; an alkoxy group; an aryloxy group; an alkylthioxy group; an arylthioxy group; an alkenyl group; a haloalkyl group; a haloalkoxy group; an arylalkyl group; a silyl group; a boron group; an amine group; an aryl group; and a heterocyclic group, or being substituted with a substituent linking two or more substituents among the substituents illustrated above, or having no substituents.

In the present specification, linking two or more substituents refers to linking hydrogen of any one substituent to another substituent. For example, linking two or more substituents may include a phenyl group and a naphthyl group being linked to become a substituent of

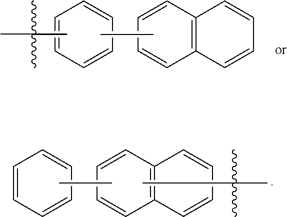

In addition, linking three substituents includes not only continuously linking (substituent 1)-(substituent 2)-(substituent 3), but also linking (substituent 2) and (substituent 3) to (substituent 1). For example, a phenyl group, a naphthyl group and an isopropyl group may be linked to become a substituent of

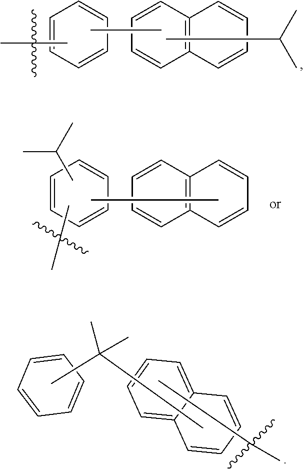

The same definition described above also applies when linking four or more substituents.

In the present specification, examples of the halogen group may include fluorine, chlorine, bromine or iodine.

In the present specification, the alkyl group may be linear or branched, and although not particularly limited thereto, the number of carbon atoms is preferably from 1 to 30. Specific examples thereof may include methyl, ethyl, propyl, n-propyl, isopropyl, butyl, n-butyl, isobutyl, tert-butyl, sec-butyl, 1-methyl-butyl, 1-ethyl-butyl, pentyl, n-pentyl, isopentyl, neopentyl, tert-pentyl, hexyl, n-hexyl, 1-methylpentyl, 2-methylpentyl, 4-methyl-2-pentyl, 3,3-dimethylbutyl, 2-ethylbutyl, heptyl, n-heptyl, 1-methylhexyl, cyclopentylmethyl, cyclohexylmethyl, octyl, n-octyl, tert-octyl, 1-methylheptyl, 2-ethylhexyl, 2-propylpentyl, n-nonyl, 2,2-dimethylheptyl, 1-ethyl-propyl, 1,1-dimethyl-propyl, isohexyl, 2-methylpentyl, 4-methylhexyl, 5-methylhexyl and the like, but are not limited thereto.

In the present specification, the cycloalkyl group is not particularly limited, but preferably has 3 to 30 carbon atoms.

Specific examples thereof may include cyclopropyl, cyclobutyl, cyclopentyl, 3-methylcyclopentyl, 2,3-dimethylcyclopentyl, cyclohexyl, 3-methylcyclohexyl, 4-methylcyclohexyl, 2,3-dimethylcyclohexyl, 3,4,5-trimethylcyclohexyl, 4-tert-butylcyclohexyl, cycloheptyl, cyclooctyl, an adamantyl group, a bicyclo[2.2.1]heptyl group, a bicyclo[2.2.1]octyl group, a norbornyl group and the like, but are not limited thereto.

In the present specification, the alkoxy group may be linear, branched or cyclic. The number of carbon atoms of the alkoxy group is not particularly limited, but is preferably from 1 to 30. Specific examples thereof may include methoxy, ethoxy, n-propoxy, isopropoxy, n-butoxy, isobutoxy, tert-butoxy, sec-butoxy, n-pentyloxy, neopentyloxy, isopentyloxy, n-hexyloxy, 3,3-dimethylbutyloxy, 2-ethylbutyloxy, n-octyloxy, n-nonyloxy, n-decyloxy, benzyloxy, p-methylbenzyloxy and the like, but are not limited thereto.

In the present specification, the alkenyl group may be linear or branched, and although not particularly limited thereto, the number of carbon atoms is preferably from 2 to 30. Specific examples thereof may include vinyl, 1-propenyl, isopropenyl, 1-butenyl, 2-butenyl, 3-butenyl, 1-pentenyl, 2-pentenyl, 3-pentenyl, 3-methyl-1-butenyl, 1,3-butadienyl, allyl, 1-phenylvinyl-1-yl, 2-phenylvinyl-1-yl, 2,2-diphenylvinyl-1-yl, 2-phenyl-2-(naphthyl-1-yl)vinyl-1-yl, 2,2-bis(diphenyl-1-yl)vinyl-1-yl, a stilbenyl group, a styrenyl group and the like, but are not limited thereto.

In the present specification, the haloalkyl group means, in the definition of the alkyl group, hydrogen of the alkyl group being substituted with at least one halogen group.

In the present specification, the haloalkoxy group means, in the definition of the alkoxy group, hydrogen of the alkoxy group being substituted with at least one halogen group.

In the present specification, the aryl group is not particularly limited, but preferably has 6 to 30 carbon atoms, and the aryl group may be monocyclic or polycyclic.

When the aryl group is a monocyclic aryl group, the number of carbon atoms is not particularly limited, but is preferably from 6 to 30. Specific examples of the monocyclic aryl group may include a phenyl group, a biphenyl group, a terphenyl group and the like, but are not limited thereto.

When the aryl group is a polycyclic aryl group, the number of carbon atoms is not particularly limited, but is preferably from 10 to 30. Specific examples of the polycyclic aryl group may include a naphthyl group, an anthracene group, a phenanthrene group, a triphenylene group, a pyrene group, a phenalene group, a perylene group, a chrysene group, a fluorene group and the like, but are not limited thereto.

In the present specification, the fluorene group may be substituted, and adjacent groups may bond to each other to form a ring.

When the fluorene group is substituted,

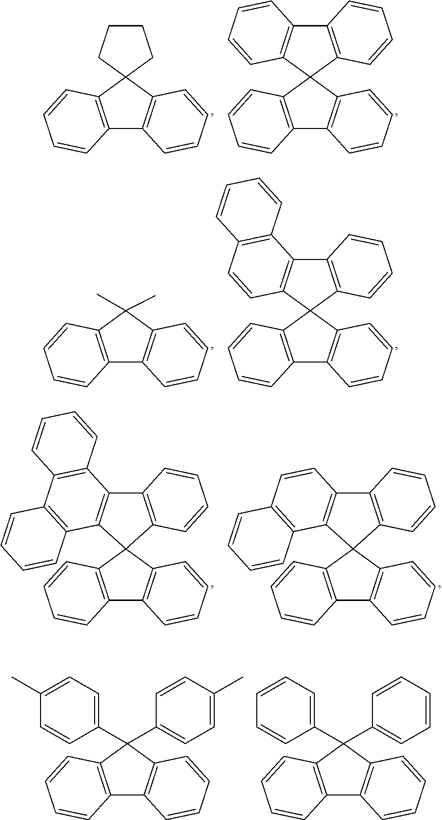

and the like may be included, however, the structure is not limited thereto.

In the present specification, an “adjacent” group may mean a substituent substituting an atom directly linked to an atom substituted by the corresponding substituent, a substituent sterically most closely positioned to the corresponding substituent, or another substituent substituting an atom substituted by the corresponding substituent. For example, two substituents substituting ortho positions in a benzene ring, and two substituents substituting the same carbon in an aliphatic ring may be interpreted as groups “adjacent” to each other.

In the present specification, the arylalkyl group means the alkyl group being substituted with an aryl group, and the examples of the aryl group and the alkyl group described above may be applied to the aryl group and the alkyl group in the arylalkyl group.

In the present specification, the aryloxy group means, in the definition of the alkoxy group, the alkyl group of alkoxy group is substituted with an aryl group, and examples of the aryloxy group may include a phenoxy group, a p-tolyloxy group, an m-tolyloxy group, a 3,5-dimethyl-phenoxy group, a 2,4,6-trimethylphenoxy group, a p-tert-butylphenoxy group, a 3-biphenyloxy group, a 4-biphenyloxy group, a 1-naphthyloxy group, a 2-naphthyloxy group, a 4-methyl-1-naphthyloxy group, a 5-methyl-2-naphthyloxy group, a 1-anthryloxy group, a 2-anthryloxy group, a 9-anthryloxy group, a 1-phenanthryloxy group, a 3-phenanthryloxy group, a 9-phenanthryloxy group and the like, but are not limited thereto.

In the present specification, the alkyl group in the alkylthioxy group is the same as the examples of the alkyl group described above. Specific examples of the alkylthioxy group may include a methylthioxy group, an ethylthioxy group, a tert-butylthioxy group, a hexylthioxy group, an octylthioxy group and the like, but are not limited thereto.

In the present specification, the aryl group in the arylthioxy group is the same as the examples of the aryl group described above. Specific examples of the arylthioxy group may include a phenylthioxy group, a 2-methylphenylthioxy group, a 4-tert-butylphenylthioxy group and the like, but are not limited thereto.

In the present specification, the heterocyclic group is a group including one or more atoms that are not carbon, that is, heteroatoms, and specifically, the heteroatom may include one or more atoms selected from the group consisting of O, N, Se, S and the like, and includes an aromatic heterocyclic group or an aliphatic heterocyclic group. The aromatic heterocyclic group may be expressed as a heteroaryl group. The number of carbon atoms of the heterocyclic group is not particularly limited, but is preferably from 2 to 30, and the heterocyclic group may be monocyclic or polycyclic. Examples of the heterocyclic group may include a thiophene group, a furan group, a pyrrole group, an imidazole group, a thiazole group, an oxazole group, an oxadiazole group, a pyridine group, a bipyridine group, a pyrimidine group, a triazine group, a triazole group, an acridine group, a pyridazine group, a pyrazine group, a quinoline group, a quinazoline group, a quinoxaline group, a phthalazine group, a pyridopyrimidine group, a pyridopyrazine group, a pyrazinopyrazine group, an isoquinoline group, an indole group, a carbazole group, a benzoxazole group, a benzimidazole group, a benzothiazole group, a benzocarbazole group, a benzothiophene group, a dibenzothiophene group, a benzofuran group, a phenanthridine group, a phenanthroline group, an isoxazole group, a thiadiazole group, a dibenzofuran group, dibenzosilole group, a phenoxanthine group, a phenoxazine group, a phenothiazine group, a decahydrobenzocarbazole group, a hexahydrocarbazole group, a dihydrobenzoazasiline group, a dihydroindenocarbazole group, a spirofluorenexanthene group, a spirofluorenethioxanthene group, a tetrahydronaphthothiophene group, a tetrahydronaphthofuran group, a tetrahydrobenzothiophene group, a tetrahydrobenzofuran group and the like, but are not limited thereto.

In the present specification, the silyl group may be an alkylsilyl group, an arylsilyl group, an alkylarylsilyl group, a heteroarylsilyl group or the like. As the alkyl group in the alkylsilyl group, the examples of the alkyl group described above may be applied, and as the aryl group in the arylsilyl group, the examples of the aryl group described above may be applied, and as the alkyl group and the aryl group in the alkylarylsilyl group, the examples of the alkyl group and the aryl group may be applied, and as the heteroaryl group in the heteroarylsilyl group, the examples of the heterocyclic group may be applied.

In the present specification, the boron group may be —BR₁₀₀R₁₀₁. R₁₀₀ and R₁₀₁ are the same as or different from each other, and may be each independently selected from the group consisting of hydrogen; deuterium; halogen; a nitrile group; a substituted or unsubstituted monocyclic or polycyclic cycloalkyl group having 3 to 30 carbon atoms; a substituted or unsubstituted linear or branched alkyl group having 1 to 30 carbon atoms; a substituted or unsubstituted monocyclic or polycyclic aryl group having 6 to 30 carbon atoms; and a substituted or unsubstituted monocyclic or polycyclic heterocyclic group having 2 to 30 carbon atoms. Specific examples of the boron group may include a dimethylboron group, a diethylboron group, a t-butylmethylboron group, a diphenylboron group and the like, but are not limited thereto.

In the present specification, the amine group may be selected from the group consisting of —NH₂, an alkylamine group, an N-alkylarylamine group, an arylamine group, an N-arylheteroarylamine group, an N-alkylheteroarylamine group and a heteroarylamine group, and although not particularly limited thereto, the number of carbon atoms is preferably from 1 to 30. Specific examples of the amine group may include a methylamine group, a dimethylamine group, an ethylamine group, a diethylamine group, a phenylamine group, a naphthylamine group, a biphenylamine group, an anthracenylamine group, a 9-methyl-anthracenylamine group, a diphenylamine group, a ditolylamine group, an N-phenyltolylamine group, a triphenylamine group, an N-phenylbiphenylamine group, an N-phenylnaphthylamine group, an N-biphenylnaphthylamine group, an N-naphthylfluorenylamine group, an N-phenylphenanthrenylamine group, an N-biphenylphenanthrenylamine group, an N-phenylfluorenylamine group, an N-phenylterphenylamine group, an N-phenanthrenylfluorenylamine group, an N-biphenylfluorenylamine group and the like, but are not limited thereto.

In the present specification, the N-alkylarylamine group means an amine group in which N of the amine group is substituted with an alkyl group and an aryl group. The alkyl group and the aryl group in the N-alkylarylamine group are the same as the examples of the alkyl group and the aryl group described above.

In the present specification, the N-arylheteroarylamine group means an amine group in which N of the amine group is substituted with an aryl group and a heteroaryl group. The aryl group and the heteroaryl group in the N-arylheteroarylamine group are the same as the examples of the aryl group and the heterocyclic group described above.

In the present specification, the N-alkylheteroarylamine group means an amine group in which N of the amine group is substituted with an alkyl group and a heteroaryl group. The alkyl group and the heteroaryl group in the N-alkylheteroarylamine group are the same as the examples of the alkyl group and the heterocyclic group described above.

In the present specification, examples of the alkylamine group include a substituted or unsubstituted monoalkylamine group, or a substituted or unsubstituted dialkylamine group. The alkyl group in the alkylamine group may be a linear or branched alkyl group. The alkylamine group including two or more alkyl groups may include linear alkyl groups, branched alkyl groups, or both linear alkyl groups and branched alkyl groups. For example, the alkyl group in the alkylamine group may be selected from among the examples of the alkyl group described above.

In the present specification, examples of the heteroarylamine group include a substituted or unsubstituted monoheteroarylamine group, or a substituted or unsubstituted diheteroarylamine group. The heteroarylamine group including two or more heteroaryl groups may include monocyclic heteroaryl groups, polycyclic heteroaryl groups, or both monocyclic heteroaryl groups and polycyclic heteroaryl groups. For example, the heteroaryl group in the heteroarylamine group may be selected from among the examples of the heterocyclic group described above.

In the present specification, the hydrocarbon ring group may be an aromatic hydrocarbon ring group, an aliphatic hydrocarbon ring group, or a fused ring group of an aromatic hydrocarbon ring and an aliphatic hydrocarbon ring, and may be selected from among the examples of the cycloalkyl group, the aryl group, and combinations thereof. Examples of the hydrocarbon ring group may include a phenyl group, a cyclohexyl group, an adamantyl group, a bicyclo[2.2.1]heptyl group, a bicyclo[2.2.1]octyl group, a tetrahydronaphthalene group, a tetrahydroanthracene group, a 1,2,3,4-tetrahydro-1,4-methanonaphthalene group, a 1,2,3,4-tetrahydro-1,4-ethanonaphthalene group and the like, but are not limited thereto.

In the present specification, the meaning of “adjacent” in the “bonding to adjacent groups to form a ring” is the same as the descriptions provided above, and the “ring” means a substituted or unsubstituted hydrocarbon ring; or a substituted or unsubstituted heteroring.

In the present specification, the hydrocarbon ring may be an aromatic hydrocarbon ring, an aliphatic hydrocarbon ring, or a fused ring of an aromatic hydrocarbon ring and an aliphatic hydrocarbon ring, and may be selected from among the examples of the cycloalkyl group, the aryl group, and combinations thereof except for those that are not monovalent. Examples of the hydrocarbon ring may include benzene, cyclohexane, adamantane, bicyclo[2.2.1]heptane, bicyclo[2.2.1]octane, tetrahydronaphthalene, tetrahydroanthracene, 1,2,3,4-tetrahydro-1,4-methanonaphthalene, 1,2,3,4-tetrahydro-1,4-ethanonaphthalene and the like, but are not limited thereto.

In addition, the aliphatic hydrocarbon ring includes all of a hydrocarbon ring including a single bond, a non-aromatic hydrocarbon ring including a multiple bond, or a ring having a form in which rings including a single bond and a multiple bond are fused. Accordingly, the ring formed with a single bond of the aliphatic hydrocarbon ring may be selected from among the examples of the cycloalkyl group except for those that are not a monovalent group, and the hydrocarbon ring including a single bond and a double bond but not an aromatic ring such as cyclopropene, cyclobutene, cyclopentene, cyclohexene, cycloheptene, cyclooctene, cyclononene, cyclodecene or cyclonorbornene also belongs to the aliphatic hydrocarbon ring.

In the present specification, the heteroring means a ring including one or more atoms that are that carbon, that is, heteroatoms, and specifically, the heteroatom may include one or more atoms selected form the group consisting of O, N, Se, S and the like. The heteroring may be monocyclic or polycyclic, and may be an aromatic heteroring; an aliphatic heteroring; a fused ring of an aromatic heteroring and an aliphatic heteroring; a fused ring of an aliphatic hydrocarbon ring, an aromatic hydrocarbon ring and an aromatic heterocyclic group, or a fused ring of an aliphatic hydrocarbon ring, an aromatic hydrocarbon ring and an aliphatic heterocyclic group, and the aromatic heteroring may be selected from among the examples of the heteroaryl group of the heterocyclic group except for those that are not monovalent.

In the present specification, the aliphatic heteroring means an aliphatic ring including one or more of heteroatoms. The aliphatic heteroring includes all of an aliphatic ring including a single bond, an aliphatic ring including a multiple bond, or an aliphatic ring having a form in which rings including a single bond and a multiple bond are fused. Examples of the aliphatic heteroring may include oxirane, tetrahydrofuran, 1,4-dioxane, pyrrolidine, piperidine, morpholine, oxepane, azokane, thiokane, tetrahydronaphthothiophene, tetrahydronaphthofuran, tetrahydrobenzothiophene, tetrahydrobenzofuran and the like, but are not limited thereto.

Unless defined otherwise in the present specification, all technical and scientific terms used in the present specification have the same meanings as terms commonly understood by those skilled in the art. Although methods and materials similar or equivalent to those described in the present specification may be used in implementing or experimenting embodiments of the present disclosure, suitable methods and materials are described later. All publications, patent applications, patents and other reference documents mentioned in the present specification are incorporated by reference in the present specification as a whole, and when conflicting, the present specification including definitions has priority unless specific passage is mentioned. Furthermore, materials, methods and examples are for illustrative purposes only, and not to limit the present specification.

According to one embodiment of the present specification, Chemical Formula 1 is represented by the following Chemical Formula 1-1.

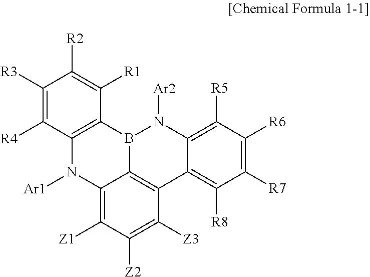

In Chemical Formula 1-1,
R5 to R8, Ar2 and Z1 to Z3 have the same definitions as in Chemical Formula 1,
R1 to R4 are the same as or different from each other, and each independently hydrogen; deuterium; a halogen group; a cyano group; a substituted or unsubstituted alkyl group; a substituted or unsubstituted cycloalkyl group; a substituted or unsubstituted alkoxy group; a substituted or unsubstituted arylalkyl group; a substituted or unsubstituted aryloxy group; a substituted or unsubstituted silyl group; a substituted or unsubstituted amine group; a substituted or unsubstituted aryl group; a substituted or unsubstituted fused ring group of an aromatic hydrocarbon ring and an aliphatic hydrocarbon ring; or a substituted or unsubstituted heterocyclic group, or bond to adjacent groups among R1 to R4 to form one selected from the group consisting of a substituted or unsubstituted aromatic hydrocarbon ring; a substituted or unsubstituted aliphatic hydrocarbon ring; a substituted or unsubstituted heteroring; and a fused ring thereof,
Ar1 is a substituted or unsubstituted cycloalkyl group; a substituted or unsubstituted aryl group; a substituted or unsubstituted fused ring group of an aromatic hydrocarbon ring and an aliphatic hydrocarbon ring; or a substituted or unsubstituted heterocyclic group, or bonds to R4 to form one selected from the group consisting of an aromatic heteroring, an aliphatic heteroring and a fused ring thereof which is substituted or unsubstituted and including one or more selected from N, S, O and Si, and
when Ar1 is a phenyl group, and R1 to R4 and R6 to R8 are hydrogen, and adjacent groups among Z1 to Z3 do not bond to each other to form a substituted or unsubstituted ring, and Ar2 and R5 form an indole group at the same time, the indole group is a substituted indole group.

According to one embodiment of the present specification, Chemical Formula 1 is represented by the following Chemical Formula 1-2.

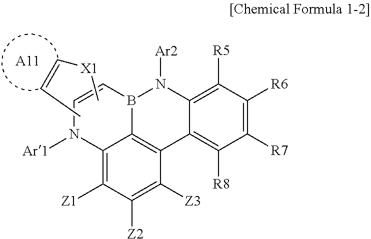

In Chemical Formula 1-2,
R5 to R8, Ar2 and Z1 to Z3 have the same definitions as in Chemical Formula 1,
X1 is CRR′, O or S,
A11 is a substituted or unsubstituted aromatic hydrocarbon ring; a substituted or unsubstituted aliphatic hydrocarbon ring; or a substituted or unsubstituted fused ring of an aromatic hydrocarbon ring and an aliphatic hydrocarbon ring,
Ar′1 is a substituted or unsubstituted cycloalkyl group; a substituted or unsubstituted aryl group; a substituted or unsubstituted fused ring group of an aromatic hydrocarbon ring and an aliphatic hydrocarbon ring; or a substituted or unsubstituted heterocyclic group, and
R and R′ are the same as or different from each other, and each independently a substituted or unsubstituted alkyl group; a substituted or unsubstituted aryl group; or a substituted or unsubstituted heterocyclic group, or bond to each other to form a substituted or unsubstituted ring.

According to one embodiment of the present specification, Chemical Formula 1-1 is represented by one of the following Chemical Formulae 1-1-1 to 1-1-36.

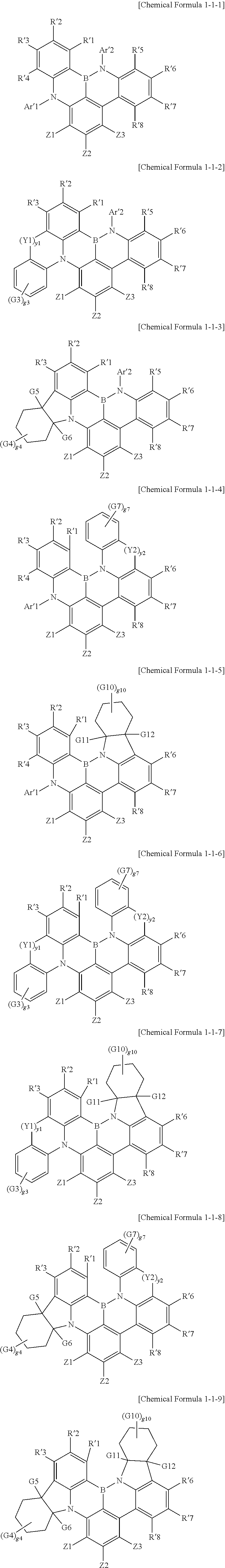

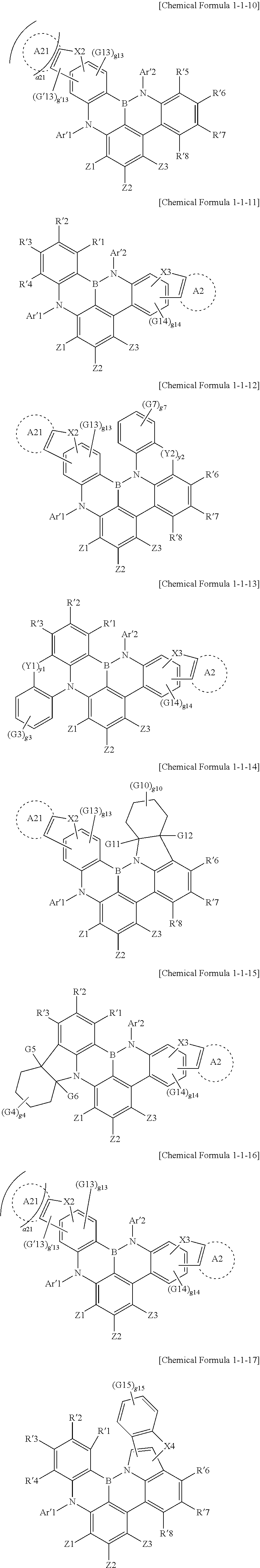

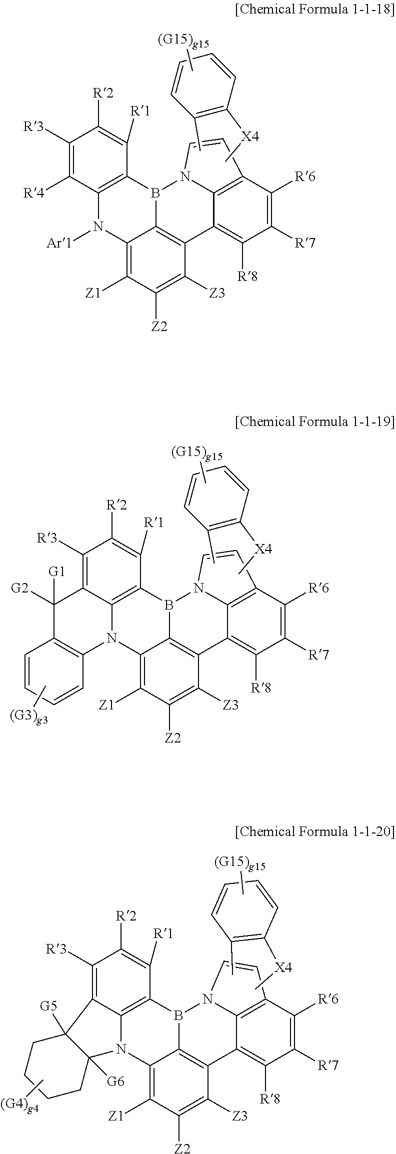

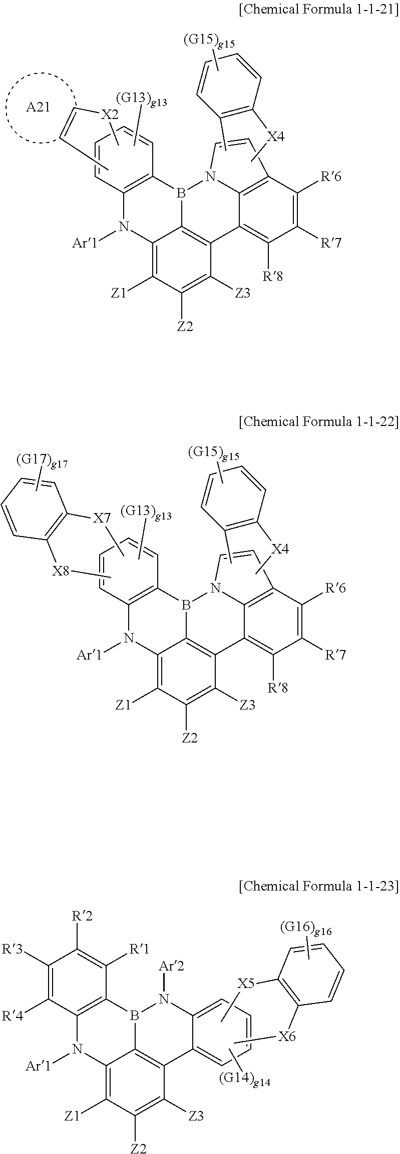

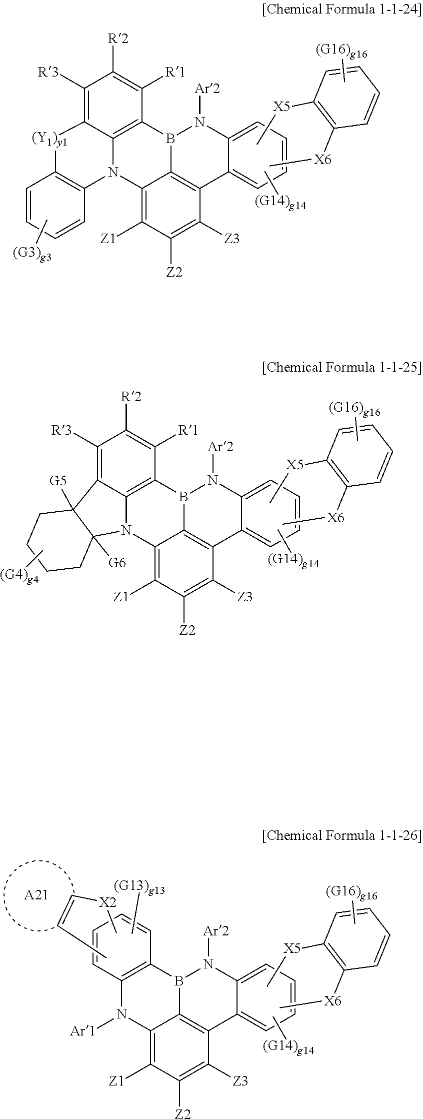

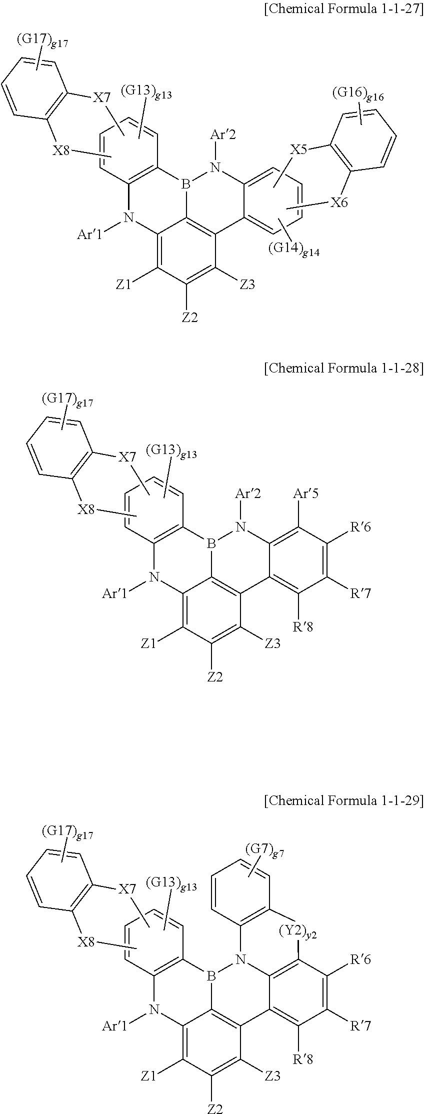

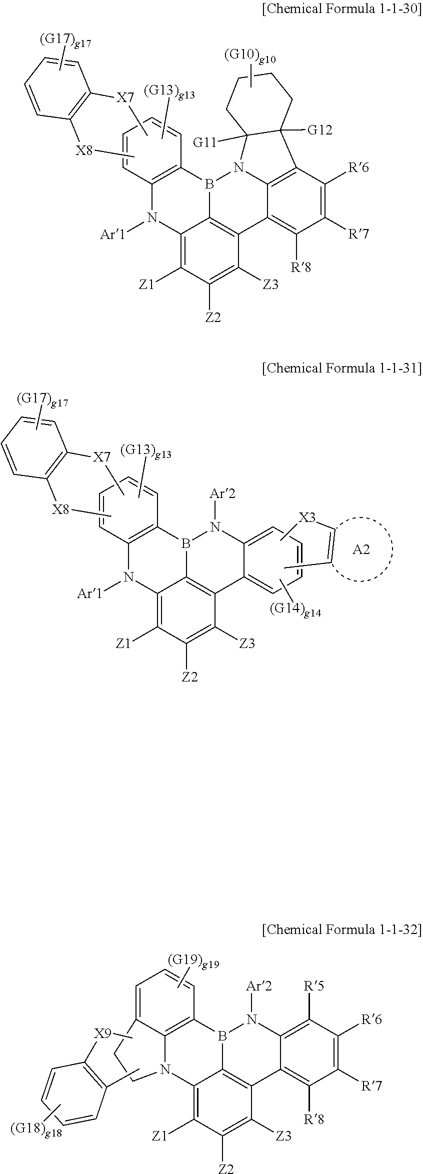

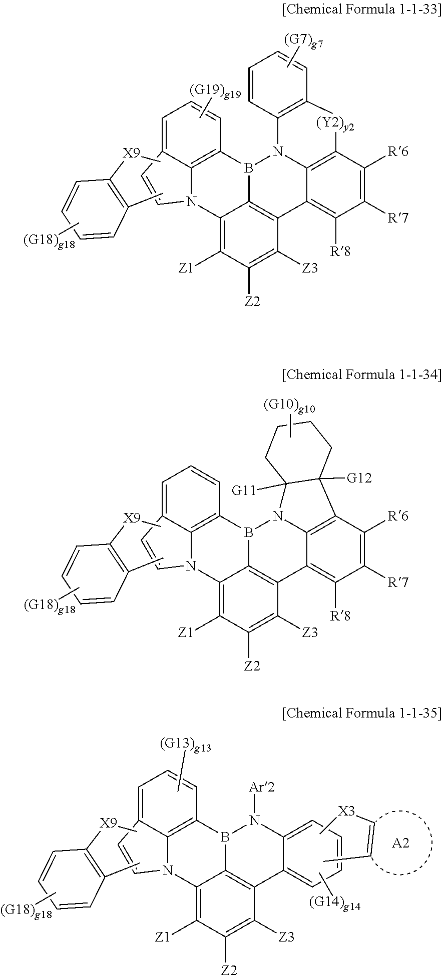

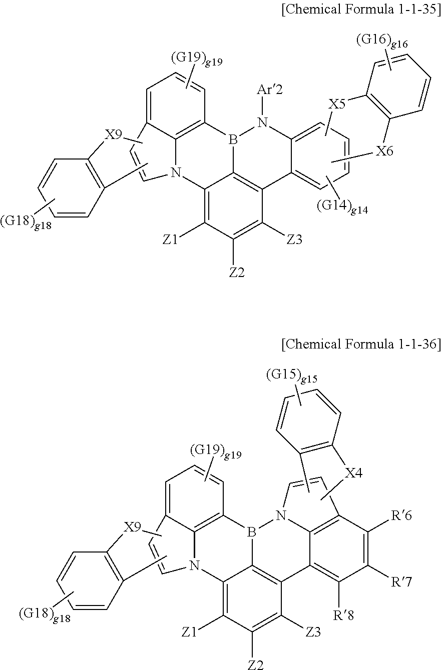

In Chemical Formulae 1-1-1 to 1-1-36,
X2 to X9 are the same as or different from each other, and each independently CRR′, NR″, O or S,
Y1 and Y2 are the same as or different from each other, and each independently CG1G2, SiG8G9, NG101, O or S,
y1 is 0 or 1, and when y1 is 0, Y1 is a direct bond,
y2 is 0 or 1, and when y2 is 0, Y2 is a direct bond,
R, R′ and R″ are the same as or different from each other, and each independently a substituted or unsubstituted alkyl group; a substituted or unsubstituted aryl group; or a substituted or unsubstituted heterocyclic group, or bond to each other to form a substituted or unsubstituted ring,
R′1 to R′8 are the same as or different from each other, and each independently hydrogen; deuterium; a halogen group; a cyano group; a substituted or unsubstituted alkyl group; a substituted or unsubstituted cycloalkyl group; a substituted or unsubstituted alkoxy group; a substituted or unsubstituted arylalkyl group; a substituted or unsubstituted aryloxy group; a substituted or unsubstituted silyl group; a substituted or unsubstituted amine group; a substituted or unsubstituted aryl group; a substituted or unsubstituted fused ring group of an aromatic hydrocarbon ring and an aliphatic hydrocarbon ring; or a substituted or unsubstituted heterocyclic group,
G1 to G19, G′13 and G101 are the same as or different from each other, and each independently hydrogen; deuterium; a halogen group; a cyano group; a substituted or unsubstituted alkyl group; a substituted or unsubstituted cycloalkyl group; a substituted or unsubstituted alkoxy group; a substituted or unsubstituted arylalkyl group; a substituted or unsubstituted aryloxy group; a substituted or unsubstituted silyl group; a substituted or unsubstituted amine group; a substituted or unsubstituted aryl group; a substituted or unsubstituted fused ring group of an aromatic hydrocarbon ring and an aliphatic hydrocarbon ring; or a substituted or unsubstituted heterocyclic group, or adjacent groups bond to each other to form a substituted or unsubstituted aromatic hydrocarbon ring; a substituted or unsubstituted aliphatic hydrocarbon ring; or a substituted or unsubstituted fused ring of an aromatic hydrocarbon ring and an aliphatic hydrocarbon ring,
g3, g7, and g15 to g18 are each an integer of 1 to 4,
g4 and g10 are each an integer of 1 to 8,
g13 and g14 are each 1 or 2,
g′13 is an integer of 0 to 2,
g19 is an integer of 1 to 3,
a21 is 0 or 1,
when g3, g4, g7, g10, and g15 to g19 are each 2 or greater, substituents in the two or more parentheses are the same as or different from each other,
when g13, g′13 and g14 are each 2, substituents in the two parentheses are the same as or different from each other,
Ar′1 and Ar′2 are the same as or different from each other, and each independently a substituted or unsubstituted cycloalkyl group; a substituted or unsubstituted aryl group; a substituted or unsubstituted fused ring group of an aromatic hydrocarbon ring and an aliphatic hydrocarbon ring; or a substituted or unsubstituted heterocyclic group,
A2 and A21 are the same as or different from each other, and each independently a substituted or unsubstituted aromatic hydrocarbon ring; a substituted or unsubstituted aliphatic hydrocarbon ring; or a substituted or unsubstituted fused ring of an aromatic hydrocarbon ring and an aliphatic hydrocarbon ring,
at least one of Z1 to Z3 is deuterium; a halogen group; a cyano group; a substituted or unsubstituted alkyl group; a substituted or unsubstituted cycloalkyl group; a substituted or unsubstituted alkoxy group; a substituted or unsubstituted arylalkyl group; a substituted or unsubstituted aryloxy group; a substituted or unsubstituted silyl group; a substituted or unsubstituted amine group; a substituted or unsubstituted aryl group; a substituted or unsubstituted fused ring group of an aromatic hydrocarbon ring and an aliphatic hydrocarbon ring; or a substituted or unsubstituted heterocyclic group, or bonds to adjacent groups to form a substituted or unsubstituted ring, and the rest are hydrogen, and
in Chemical Formulae 1-1-4, 1-1-6, 1-1-8, 1-1-12, 1-1-28 and 1-1-32,
when y2 is 1 and Y2 is O, G7 and R′6 to R′8 are hydrogen.

According to one embodiment of the present specification, Chemical Formula 1-2 is represented by one of the following Chemical Formulae 1-2-1 to 1-2-6.

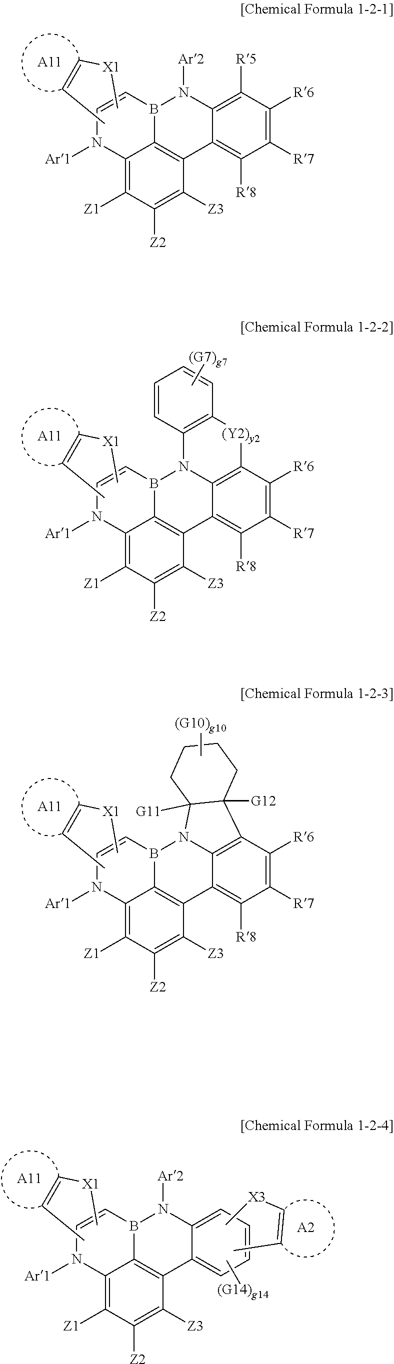

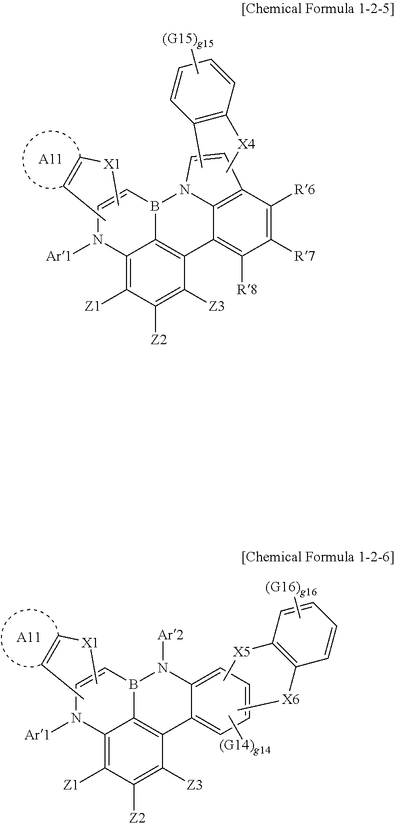

In Chemical Formulae 1-2-1 to 1-2-6,
X1, A11 and Z1 to Z3 have the same definitions as in Chemical Formula 1-2,
X3 to X6 are the same as or different from each other, and each independently CRR′, NR″, O or S,
Y2 is CG1G2, SiG8G9, NG101, O or S,
y2 is 0 or 1, and when y2 is 0, Y2 is a direct bond,
A2 is a substituted or unsubstituted aromatic hydrocarbon ring; a substituted or unsubstituted aliphatic hydrocarbon ring; or a substituted or unsubstituted fused ring of an aromatic hydrocarbon ring and an aliphatic hydrocarbon ring,
Ar′1 is a substituted or unsubstituted cycloalkyl group; a substituted or unsubstituted aryl group; a substituted or unsubstituted fused ring group of an aromatic hydrocarbon ring and an aliphatic hydrocarbon ring; or a substituted or unsubstituted heterocyclic group,
R, R′ and R″ are the same as or different from each other, and each independently a substituted or unsubstituted alkyl group; a substituted or unsubstituted aryl group; or a substituted or unsubstituted heterocyclic group, or bond to each other to form a substituted or unsubstituted ring,
R′5 to R′8 are the same as or different from each other, and each independently hydrogen; deuterium; a halogen group; a cyano group; a substituted or unsubstituted alkyl group; a substituted or unsubstituted cycloalkyl group; a substituted or unsubstituted alkoxy group; a substituted or unsubstituted arylalkyl group; a substituted or unsubstituted aryloxy group; a substituted or unsubstituted silyl group; a substituted or unsubstituted amine group; a substituted or unsubstituted aryl group; a substituted or unsubstituted fused ring group of an aromatic hydrocarbon ring and an aliphatic hydrocarbon ring; or a substituted or unsubstituted heterocyclic group,
G1, G2, G7 to G12, G14, G15, G16 and G101 are the same as or different from each other, and each independently hydrogen; deuterium; a halogen group; a cyano group; a substituted or unsubstituted alkyl group; a substituted or unsubstituted cycloalkyl group; a substituted or unsubstituted alkoxy group; a substituted or unsubstituted arylalkyl group; a substituted or unsubstituted aryloxy group; a substituted or unsubstituted silyl group; a substituted or unsubstituted amine group; a substituted or unsubstituted aryl group; a substituted or unsubstituted fused ring group of an aromatic hydrocarbon ring and an aliphatic hydrocarbon ring; or a substituted or unsubstituted heterocyclic group, or adjacent groups bond to each other to form a substituted or unsubstituted aromatic hydrocarbon ring; a substituted or unsubstituted aliphatic hydrocarbon ring; or a substituted or unsubstituted fused ring of an aromatic hydrocarbon ring and an aliphatic hydrocarbon ring,
g7, g15 and g16 are each an integer of 1 to 4,
g10 is an integer of 1 to 8,
g14 is 1 or 2,
when g7, g10, g15 and g16 are each 2 or greater, substituents in the two or more parentheses are the same as or different from each other,
when g14 is 2, substituents in the two parentheses are the same as or different from each other, and
Ar′1 and Ar′2 are the same as or different from each other, and each independently a substituted or unsubstituted cycloalkyl group; a substituted or unsubstituted aryl group; a substituted or unsubstituted fused ring group of an aromatic hydrocarbon ring and an aliphatic hydrocarbon ring; or a substituted or unsubstituted heterocyclic group.

According to one embodiment of the present specification, in Chemical Formula 1-1-4,
Y2 is CG1G2, SiG8G9, NG101, O or S, and y2 is 0 or 1,
when y2 is 0, Y2 is a direct bond,
R′1 to R′4 and R′6 to R′8 are the same as or different from each other, and each independently hydrogen; deuterium; a halogen group; a cyano group; a substituted or unsubstituted alkyl group; a substituted or unsubstituted cycloalkyl group; a substituted or unsubstituted alkoxy group; a substituted or unsubstituted arylalkyl group; a substituted or unsubstituted aryloxy group; a substituted or unsubstituted silyl group; a substituted or unsubstituted amine group; a substituted or unsubstituted aryl group; a substituted or unsubstituted fused ring group of an aromatic hydrocarbon ring and an aliphatic hydrocarbon ring; or a substituted or unsubstituted heterocyclic group,
G7s are the same as or different from each other, and each independently hydrogen; deuterium; a halogen group; a cyano group; a substituted or unsubstituted alkyl group; a substituted or unsubstituted cycloalkyl group; a substituted or unsubstituted alkoxy group; a substituted or unsubstituted arylalkyl group; a substituted or unsubstituted aryloxy group; a substituted or unsubstituted silyl group; a substituted or unsubstituted amine group; a substituted or unsubstituted aryl group; a substituted or unsubstituted fused ring group of an aromatic hydrocarbon ring and an aliphatic hydrocarbon ring; or a substituted or unsubstituted heterocyclic group, and g7 is an integer of 1 to 4,
Ar′1 is a substituted or unsubstituted cycloalkyl group; a substituted or unsubstituted aryl group; a substituted or unsubstituted fused ring group of an aromatic hydrocarbon ring and an aliphatic hydrocarbon ring; or a substituted or unsubstituted heterocyclic group,
at least one of Z1 to Z3 is deuterium; a halogen group; a cyano group; a substituted or unsubstituted alkyl group; a substituted or unsubstituted cycloalkyl group; a substituted or unsubstituted alkoxy group; a substituted or unsubstituted arylalkyl group; a substituted or unsubstituted aryloxy group; a substituted or unsubstituted silyl group; a substituted or unsubstituted amine group; a substituted or unsubstituted aryl group; a substituted or unsubstituted fused ring group of an aromatic hydrocarbon ring and an aliphatic hydrocarbon ring; or a substituted or unsubstituted heterocyclic group, and
in Chemical Formula 1-2-2,
when y2 is 1 and Y2 is O, G7 and R′6 to R′8 are hydrogen.

According to one embodiment of the present specification, in Chemical Formula 1-1-4, a case of the substituents bonding to each other to form a substituted or unsubstituted ring is excluded.

According to one embodiment of the present specification, Chemical Formula 1 is represented by one of the following Chemical Formulae 1-3 to 1-5.

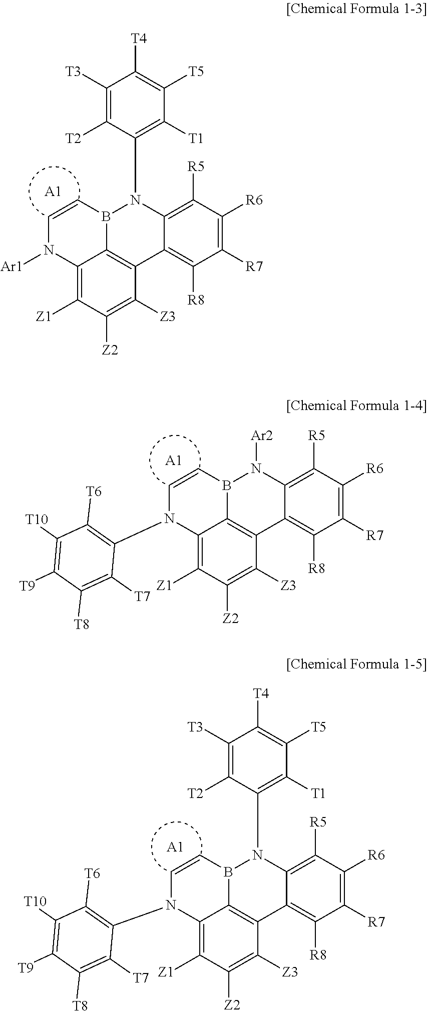

In Chemical Formulae 1-3 to 1-5,
Ar1, Ar2, A1, R5 to R8 and Z1 to Z3 have the same definitions as in Chemical Formula 1,
T1 to T10 are the same as or different from each other, and each independently hydrogen; deuterium; a halogen group; a cyano group; a substituted or unsubstituted alkyl group; a substituted or unsubstituted cycloalkyl group; a substituted or unsubstituted alkoxy group; a substituted or unsubstituted arylalkyl group; a substituted or unsubstituted aryloxy group; a substituted or unsubstituted silyl group; a substituted or unsubstituted amine group; a substituted or unsubstituted aryl group; a substituted or unsubstituted fused ring group of an aromatic hydrocarbon ring and an aliphatic hydrocarbon ring; or a substituted or unsubstituted heterocyclic group, or bond to adjacent groups to form a substituted or unsubstituted ring,
at least one of T1 and T2 is a substituted or unsubstituted alkyl group; a substituted or unsubstituted cycloalkyl group; a substituted or unsubstituted aryl group; a substituted or unsubstituted fused ring group of an aromatic hydrocarbon ring and an aliphatic hydrocarbon ring; or a substituted or unsubstituted heterocyclic group, and
at least one of T6 and T7 is a substituted or unsubstituted alkyl group; a substituted or unsubstituted cycloalkyl group; a substituted or unsubstituted aryl group; a substituted or unsubstituted fused ring group of an aromatic hydrocarbon ring and an aliphatic hydrocarbon ring; or a substituted or unsubstituted heterocyclic group.

According to one embodiment of the present specification, Chemical Formula 1 is represented by the following Chemical Formula 2.

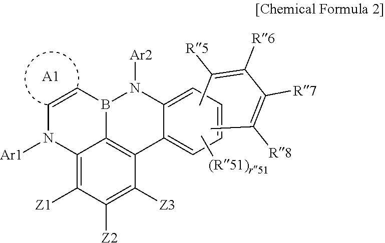

In Chemical Formula 2,
A1, Ar1 and Z1 to Z3 have the same definitions as in Chemical Formula 1,
Ar2 is a substituted or unsubstituted cycloalkyl group; a substituted or unsubstituted aryl group; a substituted or unsubstituted fused ring group of an aromatic hydrocarbon ring and an aliphatic hydrocarbon ring; or a substituted or unsubstituted heterocyclic group, or bonds to R″51 to form one selected from the group consisting of an aromatic heteroring, an aliphatic heteroring, and a fused ring thereof, each of which is substituted or unsubstituted and includes one or more selected from N, S, O and Si,
R″51 and R″5 to R″8 are the same as or different from each other, and each independently hydrogen; deuterium; a halogen group; a cyano group; a substituted or unsubstituted alkyl group; a substituted or unsubstituted cycloalkyl group; a substituted or unsubstituted alkoxy group; a substituted or unsubstituted arylalkyl group; a substituted or unsubstituted aryloxy group; a substituted or unsubstituted silyl group; a substituted or unsubstituted amine group; a substituted or unsubstituted aryl group; a substituted or unsubstituted fused ring group of an aromatic hydrocarbon ring and an aliphatic hydrocarbon ring; or a substituted or unsubstituted heterocyclic group, or bond to adjacent groups to form a substituted or unsubstituted ring,
r″51 is 1 or 2, and
when r″51 is 2, the two R″51s are the same as or different from each other.

According to one embodiment of the present specification, Chemical Formula 1-1 is represented by the following Chemical Formula 2-1.

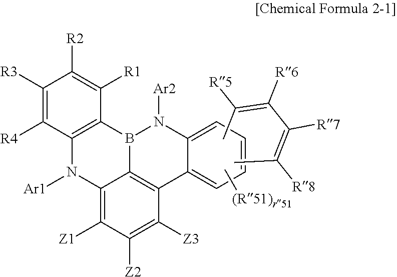

In Chemical Formula 2-1,
Ar1, R1 to R4 and Z1 to Z3 have the same definitions as in Chemical Formula 1-1,
Ar2 is a substituted or unsubstituted cycloalkyl group; a substituted or unsubstituted aryl group; a substituted or unsubstituted fused ring group of an aromatic hydrocarbon ring and an aliphatic hydrocarbon ring; or a substituted or unsubstituted heterocyclic group, or bonds to R″51 to form one selected from the group consisting of an aromatic heteroring, an aliphatic heteroring, and a fused ring thereof, each of which is substituted or unsubstituted and includes one or more selected from N, S, O and Si,
R″51 and R″5 to R″8 are the same as or different from each other, and each independently hydrogen; deuterium; a halogen group; a cyano group; a substituted or unsubstituted alkyl group; a substituted or unsubstituted cycloalkyl group; a substituted or unsubstituted alkoxy group; a substituted or unsubstituted arylalkyl group; a substituted or unsubstituted aryloxy group; a substituted or unsubstituted silyl group; a substituted or unsubstituted amine group; a substituted or unsubstituted aryl group; a substituted or unsubstituted fused ring group of an aromatic hydrocarbon ring and an aliphatic hydrocarbon ring; or a substituted or unsubstituted heterocyclic group, or bond to adjacent groups to form a substituted or unsubstituted ring,
r″51 is 1 or 2, and
when r″51 is 2, the two R″51s are the same as or different from each other.

According to one embodiment of the present specification, Chemical Formula 1-2 is represented by the following Chemical Formula 2-2.

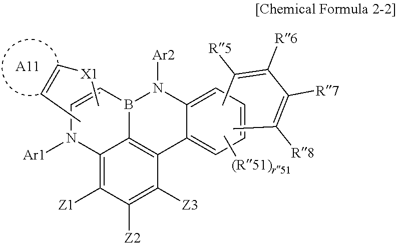

X1, A11, Ar′1 and Z1 to Z3 have the same definitions as in Chemical Formula 1-2,
Ar2 is a substituted or unsubstituted cycloalkyl group; a substituted or unsubstituted aryl group; a substituted or unsubstituted fused ring group of an aromatic hydrocarbon ring and an aliphatic hydrocarbon ring; or a substituted or unsubstituted heterocyclic group, or bonds to R″51 to form one selected from the group consisting of an aromatic heteroring, an aliphatic heteroring, and a fused ring thereof, each of which is substituted or unsubstituted and includes one or more selected from N, S, O and Si,
R″51 and R″5 to R″8 are the same as or different from each other, and each independently hydrogen; deuterium; a halogen group; a cyano group; a substituted or unsubstituted alkyl group; a substituted or unsubstituted cycloalkyl group; a substituted or unsubstituted alkoxy group; a substituted or unsubstituted arylalkyl group; a substituted or unsubstituted aryloxy group; a substituted or unsubstituted silyl group; a substituted or unsubstituted amine group; a substituted or unsubstituted aryl group; a substituted or unsubstituted fused ring group of an aromatic hydrocarbon ring and an aliphatic hydrocarbon ring; or a substituted or unsubstituted heterocyclic group, or bond to adjacent groups to form a substituted or unsubstituted ring,
r″51 is 1 or 2, and
when r″51 is 2, the two R″51s are the same as or different from each other.

According to one embodiment of the present specification, adjacent groups among Z1 to Z3 bond to each other to form a ring represented by the following Chemical Formula C-1 or C-2.

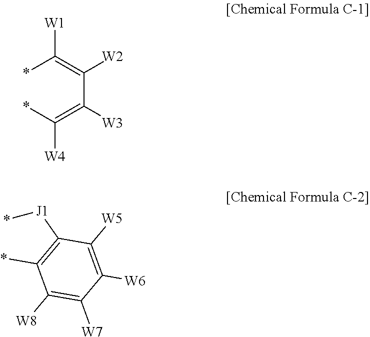

In Chemical Formulae C-1 and C-2,
J1 is O, S, NQ7, CQ8Q9 or SiQ10Q11,
W1 to W8 and Q7 to Q11 are the same as or different from each other, and each independently hydrogen; deuterium; a halogen group; a cyano group; a substituted or unsubstituted alkyl group; a substituted or unsubstituted cycloalkyl group; a substituted or unsubstituted alkoxy group; a substituted or unsubstituted arylalkyl group; a substituted or unsubstituted aryloxy group; a substituted or unsubstituted silyl group; a substituted or unsubstituted amine group; a substituted or unsubstituted aryl group; a substituted or unsubstituted fused ring group of an aromatic hydrocarbon ring and an aliphatic hydrocarbon ring; or a substituted or unsubstituted heterocyclic group, or bond to adjacent groups to form a substituted or unsubstituted ring, and
* is a site bonding to Chemical Formula 1.

According to one embodiment of the present specification, adjacent groups among W1 to W8 bond to each other to form the ring represented by Chemical Formula C-1.

According to one embodiment of the present specification, Chemical Formula C-2 is one selected from the following structures.

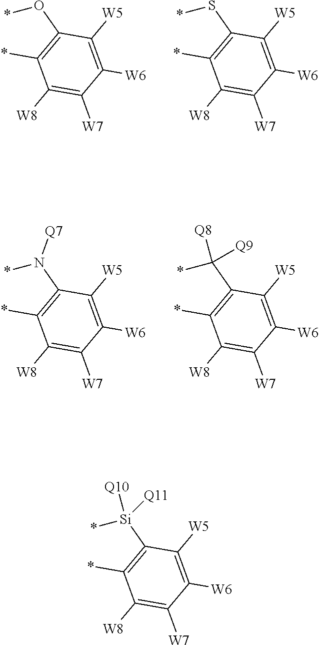

In the structures,
*, W1 to W8 and Q7 to Q11 have the same definitions as described above.

According to one embodiment of the present specification, A1 is a substituted or unsubstituted monocyclic or polycyclic aromatic hydrocarbon ring having 6 to 30 carbon atoms; a substituted or unsubstituted fused ring of a monocyclic or polycyclic aromatic hydrocarbon ring having 6 to 30 carbon atoms and a monocyclic or polycyclic aliphatic hydrocarbon ring having 3 to 30 carbon atoms; or a substituted or unsubstituted monocyclic or polycyclic heteroring having 2 to 30 carbon atoms.

According to one embodiment of the present specification, A1 is a monocyclic or polycyclic aromatic hydrocarbon ring having 6 to carbon atoms unsubstituted or substituted with a linear or branched alkyl group having 1 to 30 carbon atoms, a fused ring group of a monocyclic or polycyclic aromatic hydrocarbon ring having 6 to 30 carbon atoms and a monocyclic or polycyclic aliphatic hydrocarbon ring having 3 to 30 carbon atoms unsubstituted or substituted with a linear or branched alkyl group having 1 to 30 carbon atoms, a monocyclic or polycyclic aryl group having 6 to 30 carbon atoms, or NQ1Q2; a fused ring of a monocyclic or polycyclic aromatic hydrocarbon ring having 6 to 30 carbon atoms and a monocyclic or polycyclic aliphatic hydrocarbon ring having 3 to 30 carbon atoms unsubstituted or substituted with a linear or branched alkyl group having 1 to 30 carbon atoms; or a monocyclic or polycyclic heteroring having 2 to 30 carbon atoms unsubstituted or substituted with a linear or branched alkyl group having 1 to 30 carbon atoms or a monocyclic or polycyclic aryl group having 6 to 30 carbon atoms.

According to one embodiment of the present specification, A1 is benzene unsubstituted or substituted with a linear or branched alkyl group having 1 to 30 carbon atoms, a fused ring group of a monocyclic or polycyclic aromatic hydrocarbon ring having 6 to 30 carbon atoms and a monocyclic or polycyclic aliphatic hydrocarbon ring having 3 to 30 carbon atoms unsubstituted or substituted with a linear or branched alkyl group having 1 to 30 carbon atoms, a monocyclic or polycyclic aryl group having 6 to 30 carbon atoms, or NQ1Q2; naphthalene; indene unsubstituted or substituted with a linear or branched alkyl group having 1 to 30 carbon atoms; fluorene unsubstituted or substituted with a linear or branched alkyl group having 1 to 30 carbon atoms; tetrahydronaphthalene unsubstituted or substituted with a linear or branched alkyl group having 1 to 30 carbon atoms; dibenzofuran unsubstituted or substituted with a linear or branched alkyl group having 1 to 30 carbon atoms; dibenzothiophene unsubstituted or substituted with a linear or branched alkyl group having 1 to 30 carbon atoms; benzofuran unsubstituted or substituted with a linear or branched alkyl group having 1 to 30 carbon atoms or a monocyclic or polycyclic aryl group having 6 to 30 carbon atoms; benzothiophene unsubstituted or substituted with a linear or branched alkyl group having 1 to 30 carbon atoms or a monocyclic or polycyclic aryl group having 6 to 30 carbon atoms; benzonaphthofuran; naphthofuran; benzonaphthothiophene unsubstituted or substituted with a linear or branched alkyl group having 1 to 30 carbon atoms; tetrahydrobenzonaphthofuran unsubstituted or substituted with a linear or branched alkyl group having 1 to 30 carbon atoms; tetrahydrobenzonaphthothiophene unsubstituted or substituted with a linear or branched alkyl group having 1 to 30 carbon atoms; tetrahydrobenzofluorene unsubstituted or substituted with a linear or branched alkyl group having 1 to 30 carbon atoms; tetrahydronaphthofuran unsubstituted or substituted with a linear or branched alkyl group having 1 to 30 carbon atoms; tetrahydronaphthothiophene unsubstituted or substituted with a linear or branched alkyl group having 1 to 30 carbon atoms; naphthothiophene unsubstituted or substituted with a linear or branched alkyl group having 1 to 30 carbon atoms; or tetrahydrobenzoindene unsubstituted or substituted with a linear or branched alkyl group having 1 to 30 carbon atoms.

According to one embodiment of the present specification, A1 is benzene unsubstituted or substituted with a methyl group, a tert-butyl group, a tetramethyltetrahydronaphthyl group, a phenyl group or NQ1Q2; naphthalene; indene unsubstituted or substituted with a methyl group; fluorene unsubstituted or substituted with a methyl group; tetrahydronaphthalene unsubstituted or substituted with a methyl group; dibenzofuran unsubstituted or substituted with a methyl group or a tert-butyl group; dibenzothiophene unsubstituted or substituted with a methyl group or a tert-butyl group; benzofuran unsubstituted or substituted with a methyl group, a phenyl group or a tert-butyl group; benzothiophene unsubstituted or substituted with a methyl group, a phenyl group or a tert-butyl group; benzonaphthofuran; naphthofuran; benzonaphthothiophene unsubstituted or substituted with a tert-butyl group; tetrahydrobenzonaphthofuran unsubstituted or substituted with a methyl group; tetrahydrobenzonaphthothiophene unsubstituted or substituted with a methyl group; tetrahydrobenzofluorene unsubstituted or substituted with a methyl group; tetrahydronaphthofuran unsubstituted or substituted with a methyl group; tetrahydronaphthothiophene unsubstituted or substituted with a methyl group; naphthothiophene unsubstituted or substituted with a methyl group; or tetrahydrobenzoindene unsubstituted or substituted with a methyl group.

According to one embodiment of the present specification, Q1 and Q2 are the same as or different from each other, and each independently a monocyclic or polycyclic aryl group having 6 to 30 carbon atoms unsubstituted or substituted with a linear or branched alkyl group having 1 to 30 carbon atoms; a fused ring group of a monocyclic or polycyclic aromatic hydrocarbon ring having 6 to 30 carbon atoms and a monocyclic or polycyclic aliphatic hydrocarbon ring having 3 to 30 carbon atoms unsubstituted or substituted with a linear or branched alkyl group having 1 to 30 carbon atoms; or a monocyclic or polycyclic heterocyclic group having 2 to 30 carbon atoms.

According to one embodiment of the present specification, Q1 and Q2 are the same as or different from each other, and each independently a methyl group; a tert-butyl group; a phenyl group unsubstituted or substituted with a methyl group or a tert-butyl group; a biphenyl group unsubstituted or substituted with a methyl group or a tert-butyl group; a fluorene group unsubstituted or substituted with a methyl group; a tetrahydronaphthyl group unsubstituted or substituted with a methyl group; a dibenzofuran group; or a dibenzothiophene group.

According to one embodiment of the present specification, R5 to R8 are the same as or different from each other, and each independently hydrogen; deuterium; a substituted or unsubstituted linear or branched alkyl group having 1 to 30 carbon atoms; a substituted or unsubstituted monocyclic or polycyclic aryl group having 6 to 30 carbon atoms; or NQ3Q4, or bond to adjacent groups to form a substituted or unsubstituted monocyclic or polycyclic aliphatic hydrocarbon ring having 3 to 30 carbon atoms; a substituted or unsubstituted monocyclic or polycyclic aromatic hydrocarbon ring having 6 to 30 carbon atoms; a substituted or unsubstituted fused ring of a monocyclic or polycyclic aromatic hydrocarbon ring having 6 to 30 carbon atoms and a monocyclic or polycyclic aliphatic hydrocarbon ring having 3 to 30 carbon atoms; or a substituted or unsubstituted monocyclic or polycyclic heteroring having 2 to 30 carbon atoms.

According to one embodiment of the present specification, R5 to R8 are the same as or different from each other, and each independently hydrogen; deuterium; a linear or branched alkyl group having 1 to 30 carbon atoms; a monocyclic or polycyclic aryl group having 6 to 30 carbon atoms; or NQ3Q4, or bond to adjacent groups to form a monocyclic or polycyclic aliphatic hydrocarbon ring having 3 to 30 carbon atoms unsubstituted or substituted with a linear or branched alkyl group having 1 to 30 carbon atoms; a monocyclic or polycyclic aromatic hydrocarbon ring having 6 to 30 carbon atoms unsubstituted or substituted with a linear or branched alkyl group having 1 to 30 carbon atoms, or a monocyclic or polycyclic diarylamine group having 6 to 30 carbon atoms unsubstituted or substituted with a linear or branched alkyl group having 1 to 30 carbon atoms; a fused ring of a monocyclic or polycyclic aromatic hydrocarbon ring having 6 to 30 carbon atoms and a monocyclic or polycyclic aliphatic hydrocarbon ring having 3 to 30 carbon atoms unsubstituted or substituted with a linear or branched alkyl group having 1 to 30 carbon atoms; or a monocyclic or polycyclic heteroring having 2 to 30 carbon atoms unsubstituted or substituted with a linear or branched alkyl group having 1 to 30 carbon atoms or a monocyclic or polycyclic aryl group having 6 to 30 carbon atoms.

According to one embodiment of the present specification, R5 to R8 are the same as or different from each other, and each independently hydrogen; deuterium; a methyl group; a tert-butyl group; a phenyl group; or NQ3Q4, or bond to adjacent groups to form cyclohexane unsubstituted or substituted with a linear or branched alkyl group having 1 to 30 carbon atoms; benzene; benzofuran unsubstituted or substituted with a linear or branched alkyl group having 1 to 30 carbon atoms, or a monocyclic or polycyclic diarylamine group having 6 to 30 carbon atoms unsubstituted or substituted with a linear or branched alkyl group having 1 to 30 carbon atoms; benzothiophene unsubstituted or substituted with a linear or branched alkyl group having 1 to 30 carbon atoms, or a monocyclic or polycyclic diarylamine group having 6 to 30 carbon atoms unsubstituted or substituted with a linear or branched alkyl group having 1 to 30 carbon atoms; naphthofuran; naphthothiophene; indene unsubstituted or substituted with a linear or branched alkyl group having 1 to 30 carbon atoms, or a monocyclic or polycyclic diarylamine group having 6 to 30 carbon atoms unsubstituted or substituted with a linear or branched alkyl group having 1 to 30 carbon atoms; indole unsubstituted or substituted with a monocyclic or polycyclic aryl group having 6 to 30 carbon atoms; indoloindene unsubstituted or substituted with a linear or branched alkyl group having 1 to 30 carbon atoms; indoloindole; tetrahydronaphthofuran unsubstituted or substituted with a linear or branched alkyl group having 1 to 30 carbon atoms; tetrahydronaphthothiophene unsubstituted or substituted with a linear or branched alkyl group having 1 to 30 carbon atoms; tetrahydrobenzoindene unsubstituted or substituted with a linear or branched alkyl group having 1 to 30 carbon atoms; benzodioxine; benzooxathiine; benzodithiine; thiochromene unsubstituted or substituted with a linear or branched alkyl group having 1 to 30 carbon atoms; chromene unsubstituted or substituted with a linear or branched alkyl group having 1 to 30 carbon atoms; or dihydronaphthalene unsubstituted or substituted with a linear or branched alkyl group having 1 to 30 carbon atoms.

According to one embodiment of the present specification, R5 to R8 are the same as or different from each other, and each independently hydrogen; deuterium; a methyl group; a tert-butyl group; a phenyl group; or NQ3Q4, or bond to adjacent groups to form cyclohexane unsubstituted or substituted with a methyl group; benzene; benzofuran unsubstituted or substituted with a methyl group, a tert-butyl group, or a diphenylamine group unsubstituted or substituted with a tert-butyl group; benzothiophene unsubstituted or substituted with a methyl group, a tert-butyl group, or a diphenylamine group unsubstituted or substituted with a tert-butyl group; naphthofuran; naphthothiophene; indene unsubstituted or substituted with a methyl group, or a diphenylamine group unsubstituted or substituted with a tert-butyl group; indole unsubstituted or substituted with a phenyl group; indoloindene unsubstituted or substituted with a methyl group; indoloindole; tetrahydronaphthofuran unsubstituted or substituted with a methyl group; tetrahydronaphthothiophene unsubstituted or substituted with a methyl group; tetrahydrobenzoindene unsubstituted or substituted with a methyl group; benzodioxine; benzooxathiine; benzodithiine; thiochromene unsubstituted or substituted with a methyl group; chromene unsubstituted or substituted with a methyl group; or dihydronaphthalene unsubstituted or substituted with a methyl group.

According to one embodiment of the present specification, Q3 and Q4 are the same as or different from each other, and each independently a monocyclic or polycyclic aryl group having 6 to 30 carbon atoms unsubstituted or substituted with a linear or branched alkyl group having 1 to 30 carbon atoms; a fused ring group of a monocyclic or polycyclic aromatic hydrocarbon ring having 6 to 30 carbon atoms and a monocyclic or polycyclic aliphatic hydrocarbon ring having 3 to 30 carbon atoms unsubstituted or substituted with a linear or branched alkyl group having 1 to 30 carbon atoms; or a monocyclic or polycyclic heterocyclic group having 2 to 30 carbon atoms.

According to one embodiment of the present specification, Q3 and Q4 are the same as or different from each other, and each independently a methyl group; a tert-butyl group; a phenyl group unsubstituted or substituted with a methyl group or a tert-butyl group; a biphenyl group unsubstituted or substituted with a methyl group or a tert-butyl group; a fluorene group unsubstituted or substituted with a methyl group; a tetrahydronaphthyl group unsubstituted or substituted with a methyl group; a dibenzofuran group; or a dibenzothiophene group.

According to one embodiment of the present specification, Ar1 is a substituted or unsubstituted monocyclic or polycyclic aryl group having 6 to 30 carbon atoms; a substituted or unsubstituted fused ring group of a monocyclic or polycyclic aromatic hydrocarbon ring having 6 to 30 carbon atoms and a monocyclic or polycyclic aliphatic hydrocarbon ring having 3 to 30 carbon atoms; or a substituted or unsubstituted monocyclic or polycyclic heterocyclic group having 2 to 30 carbon atoms, or bonds to A1 to form one selected from the group consisting of a monocyclic or polycyclic aromatic heteroring having 2 to 30 carbon atoms, a monocyclic or polycyclic aliphatic heteroring having 2 to 30 carbon atoms, and a fused ring thereof, each of which is substituted or unsubstituted and includes one or more selected from N, S, O and Si.

According to one embodiment of the present specification, Ar1 is a monocyclic or polycyclic aryl group having 6 to 30 carbon atoms unsubstituted or substituted with one or more selected from the group consisting of a linear or branched alkyl group having 1 to 30 carbon atoms, a monocyclic or polycyclic aryl group having 6 to 30 carbon atoms, and a combination thereof; a fused ring group of a monocyclic or polycyclic aromatic hydrocarbon ring having 6 to 30 carbon atoms and a monocyclic or polycyclic aliphatic hydrocarbon ring having 3 to 30 carbon atoms unsubstituted or substituted with a linear or branched alkyl group having 1 to 30 carbon atoms; or a monocyclic or polycyclic heterocyclic group having 2 to 30 carbon atoms, or bonds to A1 to form one selected from the group consisting of a monocyclic or polycyclic aromatic heteroring having 2 to 30 carbon atoms, a monocyclic or polycyclic aliphatic heteroring having 2 to 30 carbon atoms, and a fused ring thereof, each of which is unsubstituted or substituted with a linear or branched alkyl group having 1 to 30 carbon atoms, a monocyclic or polycyclic cycloalkyl group having 3 to 30 carbon atoms, or a monocyclic or polycyclic aryl group having 6 to 30 carbon atoms, and includes one or more selected from N, S, O and Si.

According to one embodiment of the present specification, Ar1 is a phenyl group unsubstituted or substituted with one or more selected from the group consisting of a linear or branched alkyl group having 1 to 30 carbon atoms, a monocyclic or polycyclic aryl group having 6 to 30 carbon atoms, and a combination thereof; a biphenyl group unsubstituted or substituted with a linear or branched alkyl group having 1 to 30 carbon atoms; a terphenyl group; a fluorene group unsubstituted or substituted with a linear or branched alkyl group having 1 to 30 carbon atoms; a tetrahydronaphthyl group unsubstituted or substituted with a linear or branched alkyl group having 1 to 30 carbon atoms; a dibenzofuran group; or a dibenzothiophene group, or bonds to A1 to form dihydroacridine unsubstituted or substituted with a linear or branched alkyl group having 1 to 30 carbon atoms or a monocyclic or polycyclic aryl group having 6 to 30 carbon atoms; spiroacridinefluorene; hexahydrocarbazole unsubstituted or substituted with a linear or branched alkyl group having 1 to 30 carbon atoms; dihydrobenzoacridine unsubstituted or substituted with a linear or branched alkyl group having 1 to 30 carbon atoms or a monocyclic or polycyclic aryl group having 6 to 30 carbon atoms; hexahydrobenzoacridine unsubstituted or substituted with a linear or branched alkyl group having 1 to 30 carbon atoms or a monocyclic or polycyclic aryl group having 6 to 30 carbon atoms; spirobenzoacridine; spirotetrahydrobenzoacridinefluorene; benzofuroindole; benzothienoindole; dihydrodibenzoazasiline unsubstituted or substituted with a linear or branched alkyl group having 1 to 30 carbon atoms or a monocyclic or polycyclic aryl group having 6 to 30 carbon atoms; spirodibenzosiloledibenzoazasiline; phenoxazine; phenothiazine; dihydroindenoindole unsubstituted or substituted with a linear or branched alkyl group having 1 to 30 carbon atoms or a monocyclic or polycyclic aryl group having 6 to 30 carbon atoms; benzocarbazole; or carbazole unsubstituted or substituted with a linear or branched alkyl group having 1 to 30 carbon atoms, a monocyclic or polycyclic cycloalkyl group having 3 to 30 carbon atoms or a monocyclic or polycyclic aryl group having 6 to 30 carbon atoms.

According to one embodiment of the present specification, Ar1 is a phenyl group unsubstituted or substituted with one or more selected from the group consisting of a methyl group, an iso-propyl group, a tert-butyl group, a phenyl group and a combination thereof; a biphenyl group unsubstituted or substituted with a methyl group or a tert-butyl group; a terphenyl group; a fluorene group unsubstituted or substituted with a methyl group; a tetrahydronaphthyl group unsubstituted or substituted with a methyl group; a dibenzofuran group; or a dibenzothiophene group, or bonds to A1 to form dihydroacridine unsubstituted or substituted with a methyl group or a phenyl group; spiroacridinefluorene; hexahydrocarbazole unsubstituted or substituted with one or more selected from the group consisting of a methyl group and a tert-butyl group; dihydrobenzoacridine unsubstituted or substituted with a methyl group or a phenyl group; hexahydrobenzoacridine unsubstituted or substituted with a methyl group or a phenyl group; spirobenzoacridine; spirotetrahydrobenzoacridinefluorene; benzofuroindole; benzothienoindole; dihydrodibenzoazasiline unsubstituted or substituted with a methyl group or a phenyl group; spirodibenzosiloledibenzoazasiline; phenoxazine; phenothiazine; dihydroindenoindole unsubstituted or substituted with a methyl group or a phenyl group; benzocarbazole; or carbazole unsubstituted or substituted with a tert-butyl group, an adamantyl group or a phenyl group.

According to one embodiment of the present specification, Ar2 is a substituted or unsubstituted monocyclic or polycyclic aryl group having 6 to 30 carbon atoms; a substituted or unsubstituted fused ring group of a monocyclic or polycyclic aromatic hydrocarbon ring having 6 to 30 carbon atoms and a monocyclic or polycyclic aliphatic hydrocarbon ring having 3 to 30 carbon atoms; or a substituted or unsubstituted monocyclic or polycyclic heterocyclic group having 2 to 30 carbon atoms, or bonds to R5 to form one selected from the group consisting of a monocyclic or polycyclic aromatic heteroring having 2 to 30 carbon atoms, a monocyclic or polycyclic aliphatic heteroring having 2 to 30 carbon atoms, and a fused ring thereof, each of which is substituted or unsubstituted and includes one or more selected from N, S, O and Si.

According to one embodiment of the present specification, Ar2 is a monocyclic or polycyclic aryl group having 6 to 30 carbon atoms unsubstituted or substituted with one or more selected from the group consisting of a linear or branched alkyl group having 1 to 30 carbon atoms, a monocyclic or polycyclic aryl group having 6 to 30 carbon atoms, and a combination thereof; a fused ring group of a monocyclic or polycyclic aromatic hydrocarbon ring having 6 to 30 carbon atoms and a monocyclic or polycyclic aliphatic hydrocarbon ring having 3 to 30 carbon atoms unsubstituted or substituted with a linear or branched alkyl group having 1 to 30 carbon atoms; or a monocyclic or polycyclic heterocyclic group having 2 to 30 carbon atoms, or bonds to R5 to form one selected from the group consisting of a monocyclic or polycyclic aromatic heteroring having 2 to 30 carbon atoms, a monocyclic or polycyclic aliphatic heteroring having 2 to 30 carbon atoms, and a fused ring thereof, each of which is unsubstituted or substituted with a linear or branched alkyl group having 1 to 30 carbon atoms, a monocyclic or polycyclic cycloalkyl group having 3 to 30 carbon atoms, or a monocyclic or polycyclic aryl group having 6 to 30 carbon atoms, and includes one or more selected from N, S, O and Si.

According to one embodiment of the present specification, Ar2 is a phenyl group unsubstituted or substituted with one or more selected from the group consisting of a linear or branched alkyl group having 1 to 30 carbon atoms, a monocyclic or polycyclic aryl group having 6 to 30 carbon atoms, and a combination thereof; a biphenyl group unsubstituted or substituted with a linear or branched alkyl group having 1 to 30 carbon atoms; a terphenyl group; a fluorene group unsubstituted or substituted with a linear or branched alkyl group having 1 to 30 carbon atoms; a tetrahydronaphthyl group unsubstituted or substituted with a linear or branched alkyl group having 1 to 30 carbon atoms; a dibenzofuran group; or a dibenzothiophene group, or bonds to R5 to form dihydroquinoline unsubstituted or substituted with a linear or branched alkyl group having 1 to 30 carbon atoms or a monocyclic or polycyclic aryl group having 6 to 30 carbon atoms; spiroquinolinefluorene; hexahydroindene unsubstituted or substituted with a linear or branched alkyl group having 1 to 30 carbon atoms; dihydrobenzoquinoline unsubstituted or substituted with a linear or branched alkyl group having 1 to 30 carbon atoms or a monocyclic or polycyclic aryl group having 6 to 30 carbon atoms; hexahydrobenzoquinoline unsubstituted or substituted with a linear or branched alkyl group having 1 to 30 carbon atoms or a monocyclic or polycyclic aryl group having 6 to 30 carbon atoms; spirobenzoquinoline; spirotetrahydrobenzoquinolinefluorene; benzofuropyrrole; benzothienopyrrole; dihydrobenzoazasiline unsubstituted or substituted with a linear or branched alkyl group having 1 to 30 carbon atoms or a monocyclic or polycyclic aryl group having 6 to 30 carbon atoms; spirodibenzosilolebenzoazasiline; benzoxazine; benzothiazine; dihydroindenopyrrole unsubstituted or substituted with a linear or branched alkyl group having 1 to 30 carbon atoms or a monocyclic or polycyclic aryl group having 6 to 30 carbon atoms; benzindole; or indole unsubstituted or substituted with a linear or branched alkyl group having 1 to 30 carbon atoms, a monocyclic or polycyclic cycloalkyl group having 3 to 30 carbon atoms or a monocyclic or polycyclic aryl group having 6 to 30 carbon atoms.

According to one embodiment of the present specification, Ar2 is a phenyl group unsubstituted or substituted with one or more selected from the group consisting of a methyl group, an iso-propyl group, a tert-butyl group, a phenyl group and a combination thereof; a biphenyl group unsubstituted or substituted with a methyl group or a tert-butyl group; a terphenyl group; a fluorene group unsubstituted or substituted with a methyl group; a tetrahydronaphthyl group unsubstituted or substituted with a methyl group; a dibenzofuran group; or a dibenzothiophene group, or bonds to R5 to form dihydroquinoline unsubstituted or substituted with a methyl group or a phenyl group; spiroacridinequinoline; hexahydroindene unsubstituted or substituted with one or more selected from the group consisting of a methyl group and a tert-butyl group; dihydrobenzoquinoline unsubstituted or substituted with a methyl group or a phenyl group; hexahydrobenzoquinoline unsubstituted or substituted with a methyl group or a phenyl group; spirobenzoquinoline; spirotetrahydrobenzoquinolinefluorene; benzofuropyrrole; benzothienopyrrole; dihydrobenzoazasiline unsubstituted or substituted with a methyl group or a phenyl group; spirobenzosiloledibenzoazasiline; benzoxazine; benzothiazine; dihydroindenopyrrole unsubstituted or substituted with a methyl group or a phenyl group; benzindole; or indole unsubstituted or substituted with a tert-butyl group, an adamantyl group or a phenyl group.

According to one embodiment of the present specification, at least one of Z1 to Z3 is a substituted or unsubstituted linear or branched alkyl group having 1 to 30 carbon atoms; a substituted or unsubstituted monocyclic or polycyclic cycloalkyl group having 3 to carbon atoms; a substituted or unsubstituted monocyclic or polycyclic aryl group having 6 to 30 carbon atoms; or NQ5Q6, or forms a substituted or unsubstituted monocyclic or polycyclic aromatic hydrocarbon ring having 6 to 30 carbon atoms; or a substituted or unsubstituted monocyclic or polycyclic heteroring having 2 to 30 carbon atoms, and the rest are hydrogen.

According to one embodiment of the present specification, at least one of Z1 to Z3 is deuterium; a linear or branched alkyl group having 1 to 30 carbon atoms; a monocyclic or polycyclic cycloalkyl group having 3 to 30 carbon atoms; a monocyclic or polycyclic aryl group having 6 to 30 carbon atoms unsubstituted or substituted with deuterium, or a linear or branched alkyl group having 1 to 30 carbon atoms; or NQ5Q6, or bonds to adjacent groups to form a monocyclic or polycyclic aromatic hydrocarbon ring having 6 to 30 carbon atoms unsubstituted or substituted with a linear or branched alkyl group having 1 to 30 carbon atoms; or a monocyclic or polycyclic heteroring having 2 to 30 carbon atoms unsubstituted or substituted with one or more substituents selected from among a linear or branched alkyl group having 1 to 30 carbon atoms, a monocyclic or polycyclic aryl group having 6 to 30 carbon atoms, a fused ring group of an aromatic hydrocarbon ring and an aliphatic hydrocarbon ring, and a combination thereof, and the rest are hydrogen.

According to one embodiment of the present specification, at least one of Z1 to Z3 is deuterium; a methyl group; an iso-propyl group; a tert-butyl group; a cyclohexyl group; a phenyl group unsubstituted or substituted with deuterium, or a linear or branched alkyl group having 1 to 30 carbon atoms; or NQ5Q6, or bonds to adjacent groups to form benzene; indene unsubstituted or substituted with a linear or branched alkyl group having 1 to 30 carbon atoms; benzofuran unsubstituted or substituted with a linear or branched alkyl group having 1 to 30 carbon atoms; naphthofuran; tetrahydronaphthofuran unsubstituted or substituted with a linear or branched alkyl group having 1 to 30 carbon atoms; benzothiophene; or indole unsubstituted or substituted with one or more substituents selected from among a linear or branched alkyl group having 1 to 30 carbon atoms, a monocyclic or polycyclic aryl group having 6 to 30 carbon atoms, a fused ring group of an aromatic hydrocarbon ring and an aliphatic hydrocarbon ring, and a combination thereof, and the rest are hydrogen.

According to one embodiment of the present specification, at least one of Z1 to Z3 is deuterium; a methyl group; an iso-propyl group; a tert-butyl group; a cyclohexyl group; a phenyl group unsubstituted or substituted with deuterium or a methyl group; or NQ5Q6, or bonds to adjacent groups to form benzene; indene unsubstituted or substituted with a methyl group; benzofuran unsubstituted or substituted with a tert-butyl group; naphthofuran; tetrahydronaphthofuran unsubstituted or substituted with a methyl group; benzothiophene; or indole unsubstituted or substituted with a phenyl group, or a tetrahydronaphthyl group substituted with a methyl group, and the rest are hydrogen.

According to one embodiment of the present specification, Z2 is deuterium; a substituted or unsubstituted linear or branched alkyl group having 1 to 30 carbon atoms; a substituted or unsubstituted monocyclic or polycyclic cycloalkyl group having 3 to 30 carbon atoms; a substituted or unsubstituted monocyclic or polycyclic aryl group having 6 to 30 carbon atoms; or NQ5Q6.

According to one embodiment of the present specification, Z2 is deuterium; a linear or branched alkyl group having 1 to 30 carbon atoms; a monocyclic or polycyclic cycloalkyl group having 3 to 30 carbon atoms; a monocyclic or polycyclic aryl group having 6 to 30 carbon atoms unsubstituted or substituted with deuterium, or a linear or branched alkyl group having 1 to 30 carbon atoms; or NQ5Q6.

According to one embodiment of the present specification, Z2 is deuterium; a methyl group; an iso-propyl group; a tert-butyl group; a cyclohexyl group; a phenyl group unsubstituted or substituted with deuterium, or a linear or branched alkyl group having 1 to 30 carbon atoms; or NQ5Q6.

According to one embodiment of the present specification, Z2 is deuterium; a methyl group; an iso-propyl group; a tert-butyl group; a cyclohexyl group; a phenyl group unsubstituted or substituted with deuterium or a methyl group; or NQ5Q6.

According to one embodiment of the present specification, Z1 and Z3 are hydrogen.

According to one embodiment of the present specification, Z1 and Z3 are deuterium.

According to one embodiment of the present specification, Q5 and Q6 are the same as or different from each other, and each independently a monocyclic or polycyclic aryl group having 6 to 30 carbon atoms unsubstituted or substituted with a linear or branched alkyl group having 1 to 30 carbon atoms; a fused ring group of a monocyclic or polycyclic aromatic hydrocarbon ring having 6 to 30 carbon atoms and a monocyclic or polycyclic aliphatic hydrocarbon ring having 3 to 30 carbon atoms unsubstituted or substituted with a linear or branched alkyl group having 1 to 30 carbon atoms; or a monocyclic or polycyclic heterocyclic group having 2 to 30 carbon atoms.

According to one embodiment of the present specification, Q5 and Q6 are the same as or different from each other, and each independently a phenyl group unsubstituted or substituted with a linear or branched alkyl group having 1 to 30 carbon atoms; a biphenyl group unsubstituted or substituted with a linear or branched alkyl group having 1 to 30 carbon atoms; a fluorene group unsubstituted or substituted with a linear or branched alkyl group having 1 to 30 carbon atoms; a tetrahydronaphthyl group unsubstituted or substituted with a linear or branched alkyl group having 1 to 30 carbon atoms; a dibenzofuran group; or a dibenzothiophene group.

According to one embodiment of the present specification, Q5 and Q6 are the same as or different from each other, and each independently a phenyl group unsubstituted or substituted with a methyl group; a biphenyl group unsubstituted or substituted with a methyl group or a biphenyl group; a fluorene group unsubstituted or substituted with a methyl group; a tetrahydronaphthyl group unsubstituted or substituted with a methyl group; a dibenzofuran group; or a dibenzothiophene group.

According to one embodiment of the present specification, Z1 and G3 bond to each other to form a substituted or unsubstituted monocyclic or polycyclic heteroring having 2 to 30 carbon atoms.

According to one embodiment of the present specification, Z1 and G3 bond to each other to form a monocyclic or polycyclic heteroring having 2 to 30 carbon atoms unsubstituted or substituted with one or more substituents selected from among a linear or branched alkyl group having 1 to 30 carbon atoms, a monocyclic or polycyclic aryl group having 6 to 30 carbon atoms, a fused ring group of an aromatic hydrocarbon ring and an aliphatic hydrocarbon ring, and a combination thereof.

According to one embodiment of the present specification, Z1 and G3 bond to each other to form indole unsubstituted or substituted with one or more substituents selected from among a linear or branched alkyl group having 1 to 30 carbon atoms, a monocyclic or polycyclic aryl group having 6 to 30 carbon atoms, a fused ring group of an aromatic hydrocarbon ring and an aliphatic hydrocarbon ring, and a combination thereof.

According to one embodiment of the present specification, Z1 and G3 bond to each other to form indole unsubstituted or substituted with a phenyl group, or a tetrahydronaphthyl group substituted with a methyl group.

According to one embodiment of the present specification, A1 is a monocyclic or polycyclic aromatic hydrocarbon ring having 6 to 30 carbon atoms unsubstituted or substituted with a linear or branched alkyl group having 1 to 30 carbon atoms, a fused ring group of a monocyclic or polycyclic aromatic hydrocarbon ring having 6 to 30 carbon atoms and a monocyclic or polycyclic aliphatic hydrocarbon ring having 3 to 30 carbon atoms unsubstituted or substituted with a linear or branched alkyl group having 1 to 30 carbon atoms, a monocyclic or polycyclic aryl group having 6 to 30 carbon atoms, or NQ1Q2; a fused ring of a monocyclic or polycyclic aromatic hydrocarbon ring having 6 to 30 carbon atoms and a monocyclic or polycyclic aliphatic hydrocarbon ring having 3 to 30 carbon atoms unsubstituted or substituted with a linear or branched alkyl group having 1 to 30 carbon atoms; or a monocyclic or polycyclic heteroring having 2 to 30 carbon atoms unsubstituted or substituted with a linear or branched alkyl group having 1 to 30 carbon atoms or a monocyclic or polycyclic aryl group having 6 to 30 carbon atoms, Q1 and Q2 are the same as or different from each other and each independently a monocyclic or polycyclic aryl group having 6 to 30 carbon atoms unsubstituted or substituted with a linear or branched alkyl group having 1 to 30 carbon atoms; a fused ring group of a monocyclic or polycyclic aromatic hydrocarbon ring having 6 to 30 carbon atoms and a monocyclic or polycyclic aliphatic hydrocarbon ring having 3 to 30 carbon atoms unsubstituted or substituted with a linear or branched alkyl group having 1 to 30 carbon atoms; or a monocyclic or polycyclic heterocyclic group having 2 to 30 carbon atoms, R5 to R8 are the same as or different from each other and each independently hydrogen; deuterium; a linear or branched alkyl group having 1 to 30 carbon atoms; a monocyclic or polycyclic aryl group having 6 to 30 carbon atoms; or NQ3Q4, or bond to adjacent groups to form a monocyclic or polycyclic aliphatic hydrocarbon ring having 3 to 30 carbon atoms unsubstituted or substituted with a linear or branched alkyl group having 1 to 30 carbon atoms; a monocyclic or polycyclic aromatic hydrocarbon ring having 6 to 30 carbon atoms unsubstituted or substituted with a linear or branched alkyl group having 1 to 30 carbon atoms, or a monocyclic or polycyclic diarylamine group having 6 to 30 carbon atoms unsubstituted or substituted with a linear or branched alkyl group having 1 to 30 carbon atoms; a fused ring of a monocyclic or polycyclic aromatic hydrocarbon ring having 6 to 30 carbon atoms and a monocyclic or polycyclic aliphatic hydrocarbon ring having 3 to 30 carbon atoms unsubstituted or substituted with a linear or branched alkyl group having 1 to 30 carbon atoms; or a monocyclic or polycyclic heteroring having 2 to carbon atoms unsubstituted or substituted with a linear or branched alkyl group having 1 to 30 carbon atoms, a monocyclic or polycyclic aryl group having 6 to 30 carbon atoms, or a monocyclic or polycyclic diarylamine group having 6 to 30 carbon atoms unsubstituted or substituted with a linear or branched alkyl group having 1 to 30 carbon atoms, Q3 and Q4 are the same as or different from each other and each independently a monocyclic or polycyclic aryl group having 6 to 30 carbon atoms unsubstituted or substituted with a linear or branched alkyl group having 1 to 30 carbon atoms; a fused ring group of a monocyclic or polycyclic aromatic hydrocarbon ring having 6 to 30 carbon atoms and a monocyclic or polycyclic aliphatic hydrocarbon ring having 3 to 30 carbon atoms unsubstituted or substituted with a linear or branched alkyl group having 1 to 30 carbon atoms; or a monocyclic or polycyclic heterocyclic group having 2 to 30 carbon atoms, Ar1 is a monocyclic or polycyclic aryl group having 6 to 30 carbon atoms unsubstituted or substituted with one or more selected from the group consisting of a linear or branched alkyl group having 1 to 30 carbon atoms, a monocyclic or polycyclic aryl group having 6 to 30 carbon atoms, and a combination thereof; a fused ring group of a monocyclic or polycyclic aromatic hydrocarbon ring having 6 to 30 carbon atoms and a monocyclic or polycyclic aliphatic hydrocarbon ring having 3 to 30 carbon atoms unsubstituted or substituted with a linear or branched alkyl group having 1 to 30 carbon atoms; or a monocyclic or polycyclic heterocyclic group having 2 to 30 carbon atoms, or bonds to A1 to form one selected from the group consisting of a monocyclic or polycyclic aromatic heteroring having 2 to 30 carbon atoms, a monocyclic or polycyclic aliphatic heteroring having 2 to 30 carbon atoms, and a fused ring thereof, each of which is unsubstituted or substituted with a linear or branched alkyl group having 1 to 30 carbon atoms, a monocyclic or polycyclic cycloalkyl group having 3 to 30 carbon atoms or a monocyclic or polycyclic aryl group having 6 to 30 carbon atoms, and includes one or more selected from N, S, O and Si, Ar2 is a monocyclic or polycyclic aryl group having 6 to 30 carbon atoms unsubstituted or substituted with one or more selected from the group consisting of a linear or branched alkyl group having 1 to 30 carbon atoms, a monocyclic or polycyclic aryl group having 6 to 30 carbon atoms, and a combination thereof; a fused ring group of a monocyclic or polycyclic aromatic hydrocarbon ring having 6 to 30 carbon atoms and a monocyclic or polycyclic aliphatic hydrocarbon ring having 3 to 30 carbon atoms unsubstituted or substituted with a linear or branched alkyl group having 1 to 30 carbon atoms; or a monocyclic or polycyclic heterocyclic group having 2 to 30 carbon atoms, or bonds to R5 to form one selected from the group consisting of a monocyclic or polycyclic aromatic heteroring having 2 to 30 carbon atoms, a monocyclic or polycyclic aliphatic heteroring having 2 to 30 carbon atoms, and a fused ring thereof, each of which is unsubstituted or substituted with a linear or branched alkyl group having 1 to 30 carbon atoms, a monocyclic or polycyclic cycloalkyl group having 3 to 30 carbon atoms or a monocyclic or polycyclic aryl group having 6 to 30 carbon atoms and includes one or more selected from N, S, O and Si, at least one of Z1 to Z3 is deuterium; a linear or branched alkyl group having 1 to 30 carbon atoms; a monocyclic or polycyclic cycloalkyl group having 3 to 30 carbon atoms; a monocyclic or polycyclic aryl group having 6 to 30 carbon atoms unsubstituted or substituted with deuterium, or a linear or branched alkyl group having 1 to 30 carbon atoms; or NQ5Q6, or bonds to adjacent groups to form a monocyclic or polycyclic aromatic hydrocarbon ring having 6 to 30 carbon atoms unsubstituted or substituted with a linear or branched alkyl group having 1 to 30 carbon atoms; or a monocyclic or polycyclic heteroring having 2 to 30 carbon atoms unsubstituted or substituted with one or more substituents selected from among a linear or branched alkyl group having 1 to 30 carbon atoms, a monocyclic or polycyclic aryl group having 6 to 30 carbon atoms, a fused ring group of an aromatic hydrocarbon ring and an aliphatic hydrocarbon ring, and a combination thereof, and the rest are hydrogen, Q5 and Q6 are the same as or different from each other and each independently a monocyclic or polycyclic aryl group having 6 to 30 carbon atoms unsubstituted or substituted with a linear or branched alkyl group having 1 to 30 carbon atoms; a fused ring group of a monocyclic or polycyclic aromatic hydrocarbon ring having 6 to 30 carbon atoms and a monocyclic or polycyclic aliphatic hydrocarbon ring having 3 to 30 carbon atoms unsubstituted or substituted with a linear or branched alkyl group having 1 to 30 carbon atoms; or a monocyclic or polycyclic heterocyclic group having 2 to 30 carbon atoms, when Ar2 and R5 form a benzoxazine ring, the benzoxazine ring is an unsubstituted benzoxazine ring, and when Ar1 is a phenyl group, and A1 is substituted or unsubstituted benzene, and R6 to R8 are hydrogen, and adjacent groups among Z1 to Z3 do not bond to each other to form a substituted or unsubstituted ring, and Ar2 and R5 form an indole group at the same time, the indole group is a substituted indole group.

According to one embodiment of the present specification, R1 to R4 are the same as or different from each other, and each independently hydrogen; a substituted or unsubstituted linear or branched alkyl group having 1 to 30 carbon atoms; a substituted or unsubstituted monocyclic or polycyclic aryl group having 6 to 30 carbon atoms; or NQ3Q4, or bond to adjacent groups to form a substituted or unsubstituted monocyclic or polycyclic aliphatic hydrocarbon ring having 3 to 30 carbon atoms; a substituted or unsubstituted monocyclic or polycyclic aromatic hydrocarbon ring having 6 to 30 carbon atoms; a substituted or unsubstituted fused ring of a monocyclic or polycyclic aromatic hydrocarbon ring having 6 to 30 carbon atoms and a monocyclic or polycyclic aliphatic hydrocarbon ring having 3 to 30 carbon atoms; or a substituted or unsubstituted monocyclic or polycyclic heteroring having 2 to 30 carbon atoms.

According to one embodiment of the present specification, R1 to R4 are the same as or different from each other, and each independently hydrogen; a linear or branched alkyl group having 1 to 30 carbon atoms; a monocyclic or polycyclic aryl group having 6 to 30 carbon atoms; or NQ3Q4, or bond to adjacent groups to form a monocyclic or polycyclic aliphatic hydrocarbon ring having 3 to 30 carbon atoms unsubstituted or substituted with a linear or branched alkyl group having 1 to 30 carbon atoms; a monocyclic or polycyclic aromatic hydrocarbon ring having 6 to 30 carbon atoms unsubstituted or substituted with a linear or branched alkyl group having 1 to 30 carbon atoms; a fused ring of a monocyclic or polycyclic aromatic hydrocarbon ring having 6 to 30 carbon atoms and a monocyclic or polycyclic aliphatic hydrocarbon ring having 3 to 30 carbon atoms unsubstituted or substituted with a linear or branched alkyl group having 1 to 30 carbon atoms; or a monocyclic or polycyclic heteroring having 2 to 30 carbon atoms unsubstituted or substituted with a linear or branched alkyl group having 1 to 30 carbon atoms or a monocyclic or polycyclic aryl group having 6 to 30 carbon atoms.

According to one embodiment of the present specification, R1 to R4 are the same as or different from each other, and each independently hydrogen; a methyl group; a tert-butyl group; a phenyl group; or NQ3Q4, or bond to adjacent groups to form cyclohexane unsubstituted or substituted with a linear or branched alkyl group having 1 to 30 carbon atoms; benzene; benzofuran unsubstituted or substituted with a linear or branched alkyl group having 1 to 30 carbon atoms; benzothiophene unsubstituted or substituted with a linear or branched alkyl group having 1 to 30 carbon atoms; naphthofuran; naphthothiophene; indene unsubstituted or substituted with a linear or branched alkyl group having 1 to 30 carbon atoms; indole unsubstituted or substituted with a monocyclic or polycyclic aryl group having 6 to 30 carbon atoms; indoloindene unsubstituted or substituted with a linear or branched alkyl group having 1 to 30 carbon atoms; indoloindole; tetrahydronaphthofuran unsubstituted or substituted with a linear or branched alkyl group having 1 to 30 carbon atoms; tetrahydronaphthothiophene unsubstituted or substituted with a linear or branched alkyl group having 1 to 30 carbon atoms; tetrahydrobenzoindene unsubstituted or substituted with a linear or branched alkyl group having 1 to 30 carbon atoms; benzodioxine; benzooxathiine; benzodithiine; thiochromene unsubstituted or substituted with a linear or branched alkyl group having 1 to 30 carbon atoms; chromene unsubstituted or substituted with a linear or branched alkyl group having 1 to 30 carbon atoms; or dihydronaphthalene unsubstituted or substituted with a linear or branched alkyl group having 1 to 30 carbon atoms.

According to one embodiment of the present specification, R1 to R4 are the same as or different from each other, and each independently hydrogen; a methyl group; a tert-butyl group; a phenyl group; or NQ3Q4, or bond to adjacent groups to form cyclohexane unsubstituted or substituted with a methyl group; benzene; benzofuran unsubstituted or substituted with a methyl group or a tert-butyl group; benzothiophene unsubstituted or substituted with a methyl group or a tert-butyl group; naphthofuran; naphthothiophene; indene unsubstituted or substituted with a methyl group; indole unsubstituted or substituted with a phenyl group; indoloindene unsubstituted or substituted with a methyl group; indoloindole; tetrahydronaphthofuran unsubstituted or substituted with a methyl group; tetrahydronaphthothiophene unsubstituted or substituted with a methyl group; tetrahydrobenzoindene unsubstituted or substituted with a methyl group; benzodioxine; benzooxathiine; benzodithiine; thiochromene unsubstituted or substituted with a methyl group; chromene unsubstituted or substituted with a methyl group; or dihydronaphthalene unsubstituted or substituted with a methyl group.

According to one embodiment of the present specification, Q3 and Q4 have the same definitions as described above.

According to one embodiment of the present specification, R4 bonds to Ar1 to form one selected from the group consisting of a monocyclic or polycyclic aromatic heteroring having 2 to 30 carbon atoms, a monocyclic or polycyclic aliphatic heteroring having 2 to 30 carbon atoms and a fused ring thereof which is substituted or unsubstituted and including one or more selected from N, S, O and Si.

According to one embodiment of the present specification, R4 bonds to Ar1 to form one selected from the group consisting of a monocyclic or polycyclic aromatic heteroring having 2 to 30 carbon atoms, a monocyclic or polycyclic aliphatic heteroring having 2 to carbon atoms, and a fused ring thereof, each of which is unsubstituted or substituted with a linear or branched alkyl group having 1 to 30 carbon atoms, a monocyclic or polycyclic cycloalkyl group having 3 to 30 carbon atoms or a monocyclic or polycyclic aryl group having 6 to 30 carbon atoms and includes one or more selected from N, S, O and Si.

According to one embodiment of the present specification, R4 bonds to Ar1 to form dihydroquinoline unsubstituted or substituted with a linear or branched alkyl group having 1 to 30 carbon atoms or a monocyclic or polycyclic aryl group having 6 to 30 carbon atoms; spiroquinolinefluorene; hexahydroindene unsubstituted or substituted with a linear or branched alkyl group having 1 to 30 carbon atoms; dihydrobenzoquinoline unsubstituted or substituted with a linear or branched alkyl group having 1 to 30 carbon atoms or a monocyclic or polycyclic aryl group having 6 to 30 carbon atoms; hexahydrobenzoquinoline unsubstituted or substituted with a linear or branched alkyl group having 1 to 30 carbon atoms or a monocyclic or polycyclic aryl group having 6 to 30 carbon atoms; spirobenzoquinoline; spirotetrahydrobenzoquinolinefluorene; benzofuropyrrole; benzothienopyrrole; dihydrobenzoazasiline unsubstituted or substituted with a linear or branched alkyl group having 1 to 30 carbon atoms or a monocyclic or polycyclic aryl group having 6 to 30 carbon atoms; spirodibenzosilolebenzoazasiline; benzoxazine; benzothiazine; dihydroindenopyrrole unsubstituted or substituted with a linear or branched alkyl group having 1 to 30 carbon atoms or a monocyclic or polycyclic aryl group having 6 to 30 carbon atoms; benzindole; or indole unsubstituted or substituted with a linear or branched alkyl group having 1 to 30 carbon atoms, a monocyclic or polycyclic cycloalkyl group having 3 to 30 carbon atoms or a monocyclic or polycyclic aryl group having 6 to 30 carbon atoms.

According to one embodiment of the present specification, R4 bonds to Ar1 to form dihydroquinoline unsubstituted or substituted with a methyl group or a phenyl group; spiroacridinequinoline; hexahydroindene unsubstituted or substituted with one or more selected from the group consisting of a methyl group and a tert-butyl group; dihydrobenzoquinoline unsubstituted or substituted with a methyl group or a phenyl group; hexahydrobenzoquinoline unsubstituted or substituted with a methyl group or a phenyl group; spirobenzoquinoline; spirotetrahydrobenzoquinolinefluorene; benzofuropyrrole; benzothienopyrrole; dihydrobenzoazasiline unsubstituted or substituted with a methyl group or a phenyl group; spirobenzosiloledibenzoazasiline; benzoxazine; benzothiazine; dihydroindenopyrrole unsubstituted or substituted with a methyl group or a phenyl group; benzindole; or indole unsubstituted or substituted with a tert-butyl group, an adamantyl group or a phenyl group.

According to one embodiment of the present specification, Chemical Formula 1 is one selected from the following compounds.

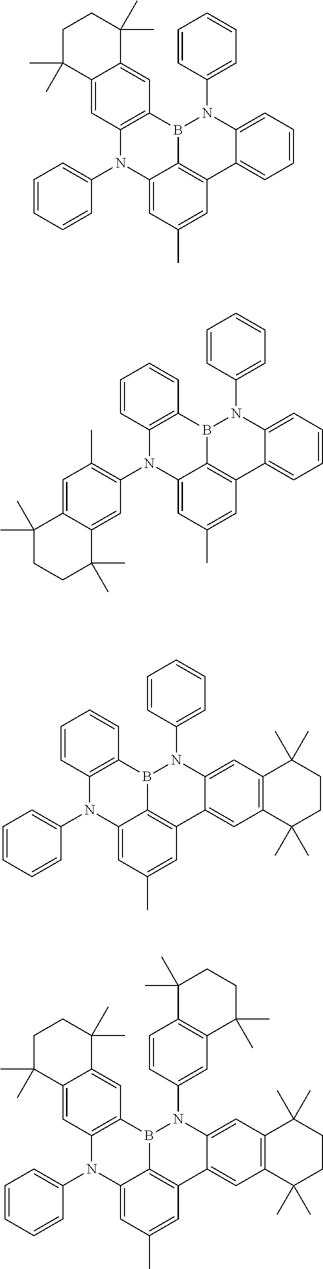 [SMILES: Cc1cc2c3c(c1)N(c1ccccc1)c1cc4c(cc1B3N(c1ccccc1)c1ccccc1-2)C(C)(C)CCC4(C)C ; Cc1cc2c3c(c1)N(c1cc4c(cc1C)C(C)(C)CCC4(C)C)c1ccccc1B3N(c1ccccc1)c1ccccc1-2 ; Cc1cc2c3c(c1)N(c1ccccc1)c1ccccc1B3N(c1ccccc1)c1cc3c(cc1-2)C(C)(C)CCC3(C)C ; Cc1cc2c3c(c1)N(c1ccccc1)c1cc4c(cc1B3N(c1ccc3c(c1)C(C)(C)CCC3(C)C)c1cc3c(cc1-2)C(C)(C)CCC3(C)C)C(C)(C)CCC4(C)C]

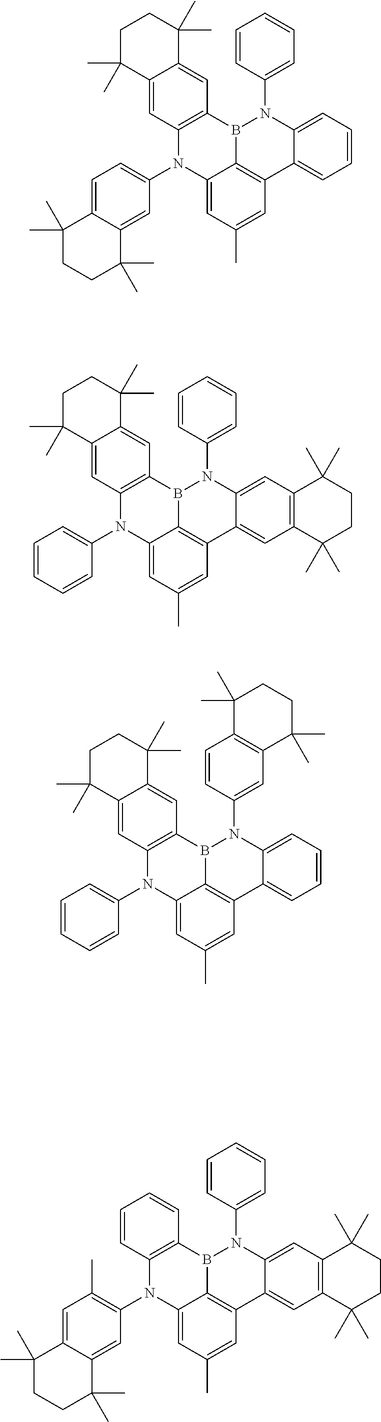

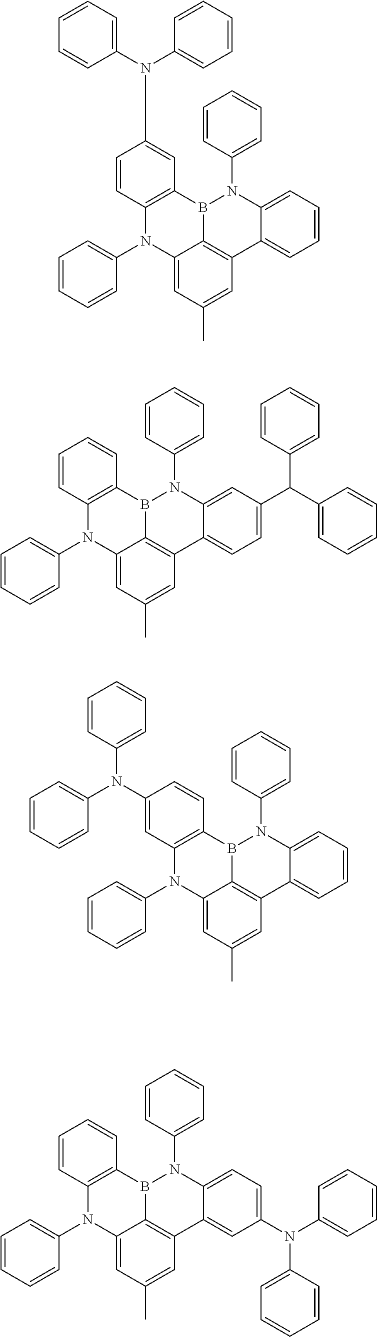 [SMILES: Cc1cc2c3c(c1)N(c1ccccc1)c1ccc(N(c4ccccc4)c4ccccc4)cc1B3N(c1ccccc1)c1ccccc1-2 ; Cc1cc2c3c(c1)N(c1ccccc1)c1ccccc1B3N(c1ccccc1)c1cc(C(c3ccccc3)c3ccccc3)ccc1-2 ; Cc1cc2c3c(c1)N(c1ccccc1)c1cc(N(c4ccccc4)c4ccccc4)ccc1B3N(c1ccccc1)c1ccccc1-2 ; Cc1cc2c3c(c1)N(c1ccccc1)c1ccccc1B3N(c1ccccc1)c1ccc(N(c3ccccc3)c3ccccc3)cc1-2]

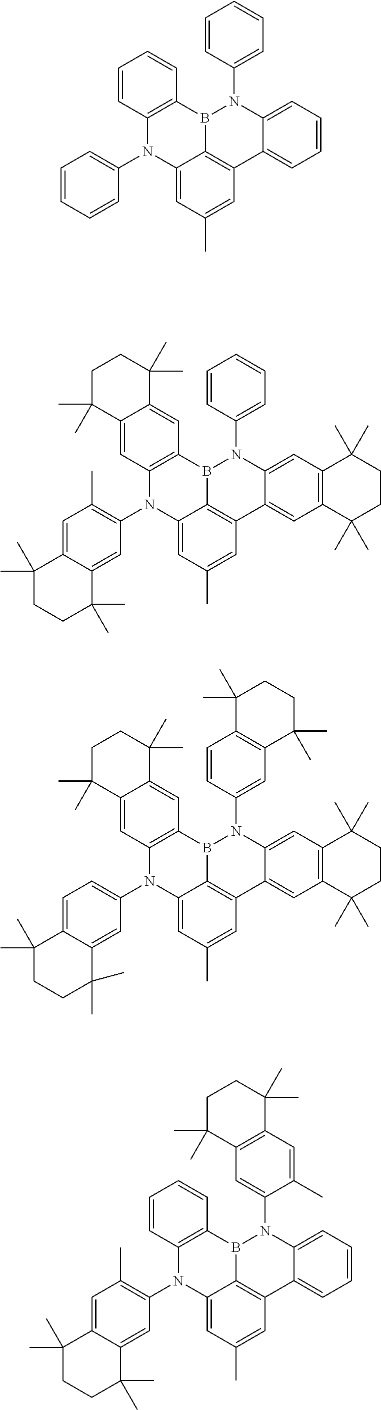 [SMILES: Cc1cc2c3c(c1)N(c1ccccc1)c1ccccc1B3N(c1ccccc1)c1ccccc1-2 ; Cc1cc2c3c(c1)N(c1cc4c(cc1C)C(C)(C)CCC4(C)C)c1cc4c(cc1B3N(c1ccccc1)c1cc3c(cc1-2)C(C)(C)CCC3(C)C)C(C)(C)CCC4(C)C ; Cc1cc2c3c(c1)N(c1ccc4c(c1)C(C)(C)CCC4(C)C)c1cc4c(cc1B3N(c1ccc3c(c1)C(C)(C)CCC3(C)C)c1cc3c(cc1-2)C(C)(C)CCC3(C)C)C(C)(C)CCC4(C)C ; Cc1cc2c3c(c1)N(c1cc4c(cc1C)C(C)(C)CCC4(C)C)c1ccccc1B3N(c1cc3c(cc1C)C(C)(C)CCC3(C)C)c1ccccc1-2]

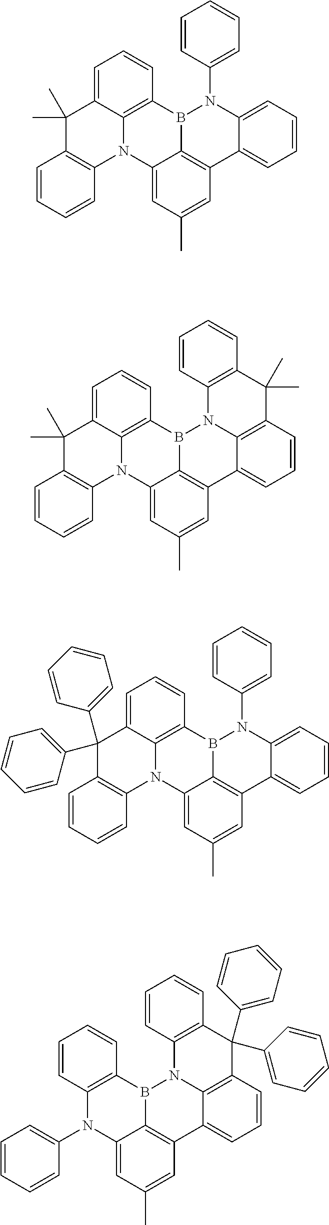

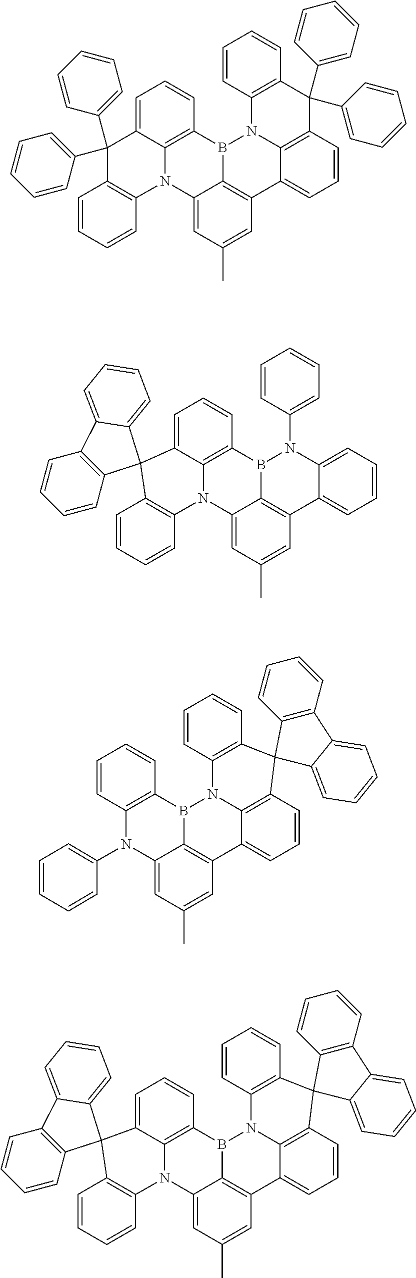 [SMILES: Cc1cc2c3c(c1)N1c4ccccc4C(c4ccccc4)(c4ccccc4)c4cccc(c41)B3N1c3ccccc3C(c3ccccc3)(c3ccccc3)c3cccc-2c31 ; Cc1cc2c3c(c1)N1c4ccccc4C4(c5ccccc5-c5ccccc54)c4cccc(c41)B3N(c1ccccc1)c1ccccc1-2 ; Cc1cc2c3c(c1)N(c1ccccc1)c1ccccc1B3N1c3ccccc3C3(c4ccccc4-c4ccccc43)c3cccc-2c31 ; Cc1cc2c3c(c1)N1c4ccccc4C4(c5ccccc5-c5ccccc54)c4cccc(c41)B3N1c3ccccc3C3(c4ccccc4-c4ccccc43)c3cccc-2c31]

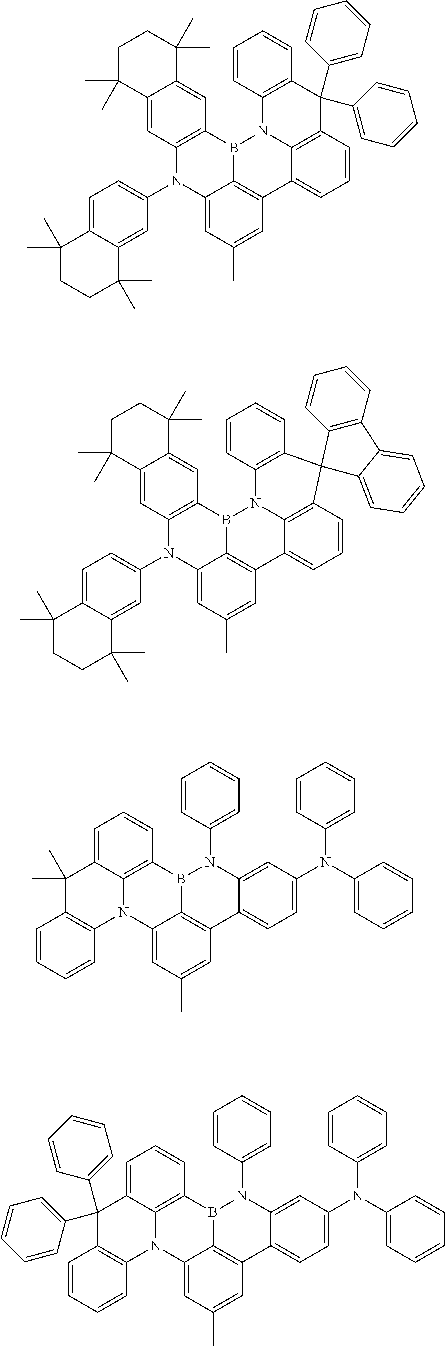 [SMILES: Cc1cc2c3c(c1)N(c1ccc4c(c1)C(C)(C)CCC4(C)C)c1cc4c(cc1B3N1c3ccccc3C(c3ccccc3)(c3ccccc3)c3cccc-2c31)C(C)(C)CCC4(C)C ; Cc1cc2c3c(c1)N(c1ccc4c(c1)C(C)(C)CCC4(C)C)c1cc4c(cc1B3N1c3ccccc3C3(c5ccccc5-c5ccccc53)c3cccc-2c31)C(C)(C)CCC4(C)C ; Cc1cc2c3c(c1)N1c4ccccc4C(C)(C)c4cccc(c41)B3N(c1ccccc1)c1cc(N(c3ccccc3)c3ccccc3)ccc1-2 ; Cc1cc2c3c(c1)N1c4ccccc4C(c4ccccc4)(c4ccccc4)c4cccc(c41)B3N(c1ccccc1)c1cc(N(c3ccccc3)c3ccccc3)ccc1-2]

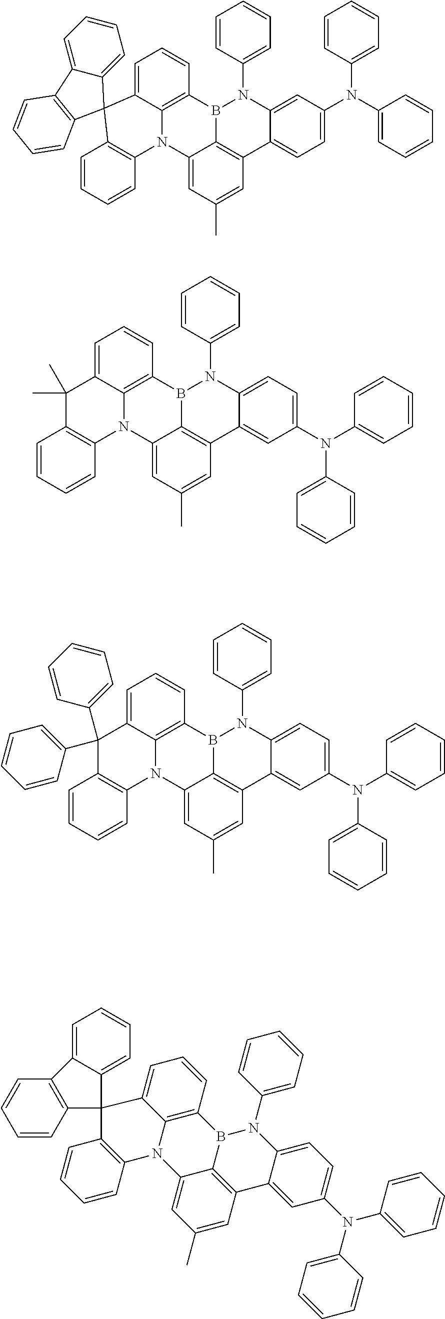

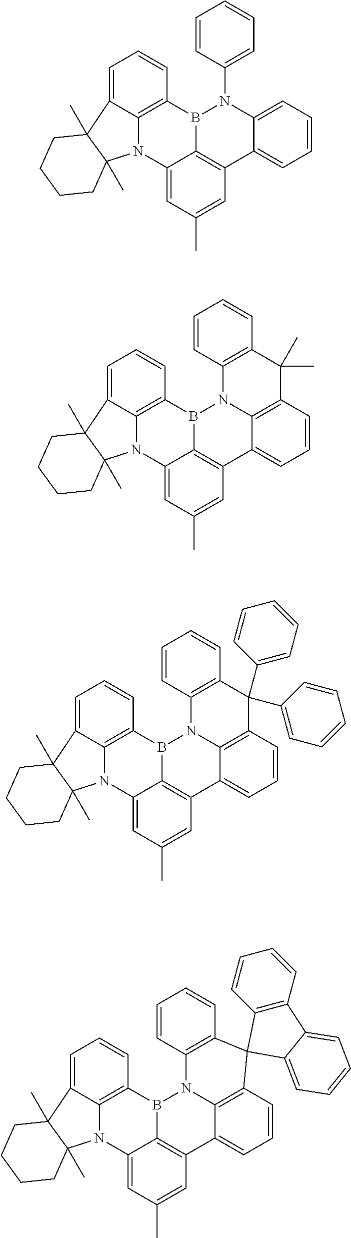 [SMILES: Cc1cc2c3c(c1)N1c4c(cccc4C4(C)CCCCC14C)B3N(c1ccccc1)c1ccccc1-2 ; Cc1cc2c3c(c1)N1c4c(cccc4C4(C)CCCCC14C)B3N1c3ccccc3C(C)(C)c3cccc-2c31 ; Cc1cc2c3c(c1)N1c4c(cccc4C4(C)CCCCC14C)B3N1c3ccccc3C(c3ccccc3)(c3ccccc3)c3cccc-2c31 ; Cc1cc2c3c(c1)N1c4c(cccc4C4(C)CCCCC14C)B3N1c3ccccc3C3(c4ccccc4-c4ccccc43)c3cccc-2c31]

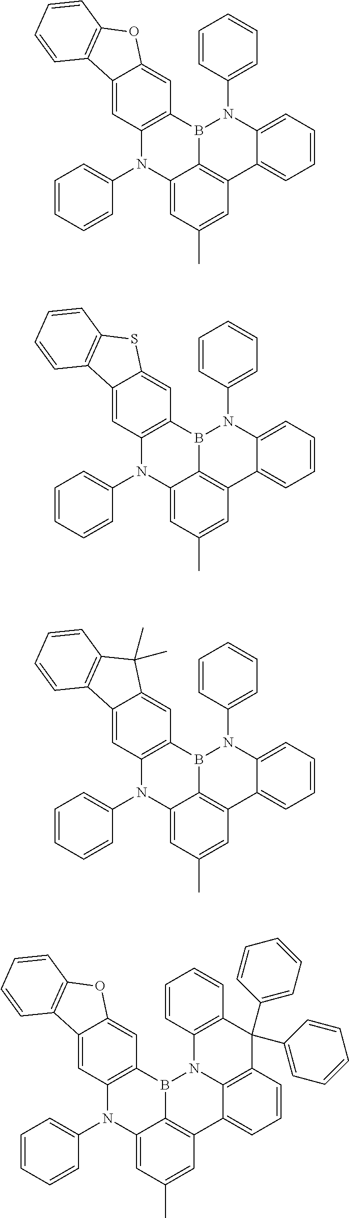 [SMILES: Cc1cc2c3c(c1)N(c1ccccc1)c1cc4c(cc1B3N(c1ccccc1)c1ccccc1-2)oc1ccccc14 ; Cc1cc2c3c(c1)N(c1ccccc1)c1cc4c(cc1B3N(c1ccccc1)c1ccccc1-2)sc1ccccc14 ; Cc1cc2c3c(c1)N(c1ccccc1)c1cc4c(cc1B3N(c1ccccc1)c1ccccc1-2)C(C)(C)c1ccccc1-4 ; Cc1cc2c3c(c1)N(c1ccccc1)c1cc4c(cc1B3N1c3ccccc3C(c3ccccc3)(c3ccccc3)c3cccc-2c31)oc1ccccc14]

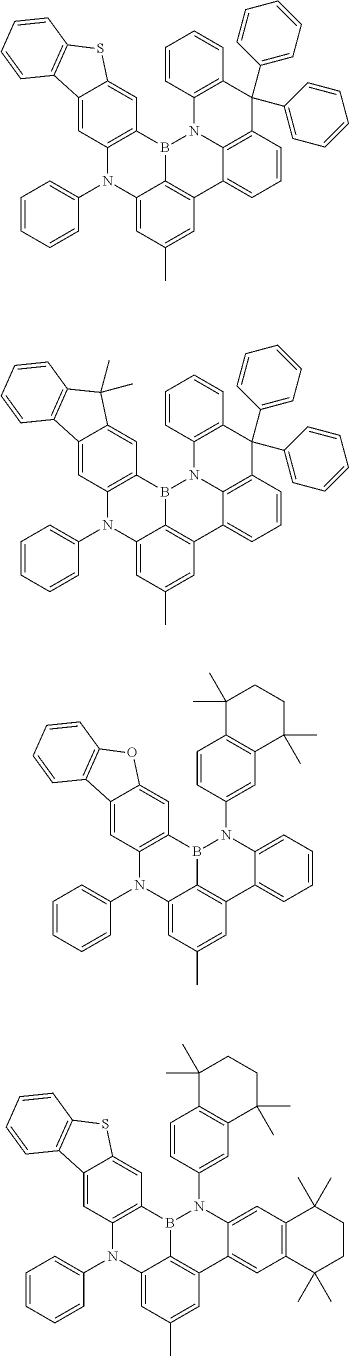 [SMILES: Cc1cc2c3c(c1)N(c1ccccc1)c1cc4c(cc1B3N1c3ccccc3C(c3ccccc3)(c3ccccc3)c3cccc-2c31)sc1ccccc14 ; Cc1cc2c3c(c1)N(c1ccccc1)c1cc4c(cc1B3N1c3ccccc3C(c3ccccc3)(c3ccccc3)c3cccc-2c31)C(C)(C)c1ccccc1-4 ; Cc1cc2c3c(c1)N(c1ccccc1)c1cc4c(cc1B3N(c1ccc3c(c1)C(C)(C)CCC3(C)C)c1ccccc1-2)oc1ccccc14 ; Cc1cc2c3c(c1)N(c1ccccc1)c1cc4c(cc1B3N(c1ccc3c(c1)C(C)(C)CCC3(C)C)c1cc3c(cc1-2)C(C)(C)CCC3(C)C)sc1ccccc14]

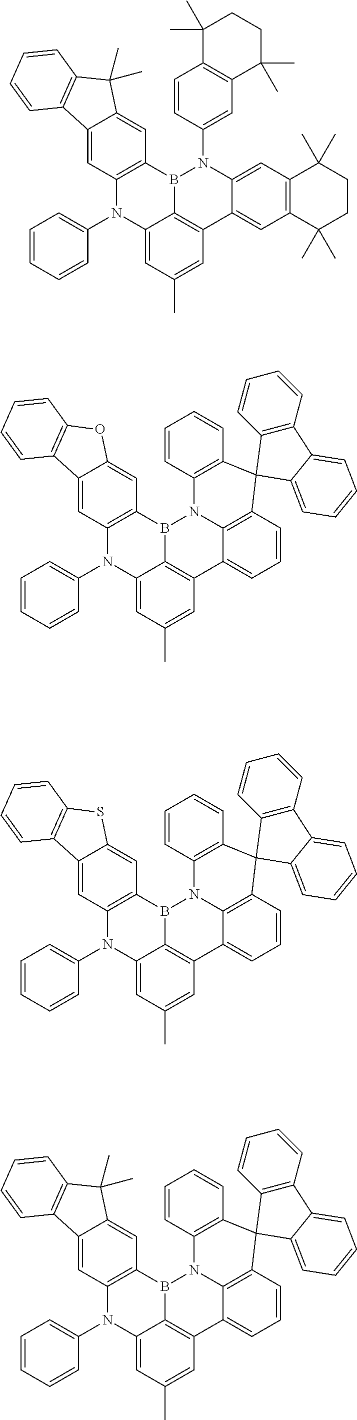 [SMILES: Cc1cc2c3c(c1)N(c1ccccc1)c1cc4c(cc1B3N(c1ccc3c(c1)C(C)(C)CCC3(C)C)c1cc3c(cc1-2)C(C)(C)CCC3(C)C)C(C)(C)c1ccccc1-4 ; Cc1cc2c3c(c1)N(c1ccccc1)c1cc4c(cc1B3N1c3ccccc3C3(c5ccccc5-c5ccccc53)c3cccc-2c31)oc1ccccc14 ; Cc1cc2c3c(c1)N(c1ccccc1)c1cc4c(cc1B3N1c3ccccc3C3(c5ccccc5-c5ccccc53)c3cccc-2c31)sc1ccccc14 ; Cc1cc2c3c(c1)N(c1ccccc1)c1cc4c(cc1B3N1c3ccccc3C3(c5ccccc5-c5ccccc53)c3cccc-2c31)C(C)(C)c1ccccc1-4]

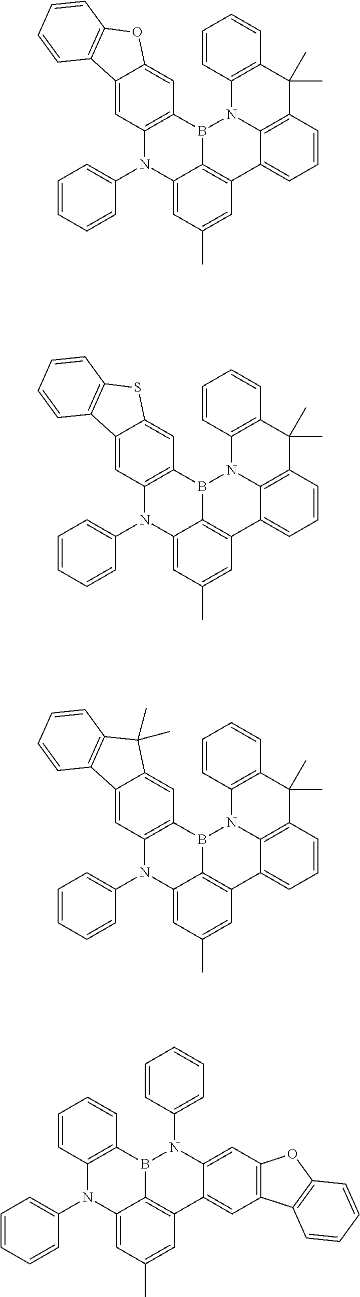 [SMILES: Cc1cc2c3c(c1)N(c1ccccc1)c1cc4c(cc1B3N1c3ccccc3C(C)(C)c3cccc-2c31)oc1ccccc14 ; Cc1cc2c3c(c1)N(c1ccccc1)c1cc4c(cc1B3N1c3ccccc3C(C)(C)c3cccc-2c31)sc1ccccc14 ; Cc1cc2c3c(c1)N(c1ccccc1)c1cc4c(cc1B3N1c3ccccc3C(C)(C)c3cccc-2c31)C(C)(C)c1ccccc1-4 ; Cc1cc2c3c(c1)N(c1ccccc1)c1ccccc1B3N(c1ccccc1)c1cc3oc4ccccc4c3cc1-2]

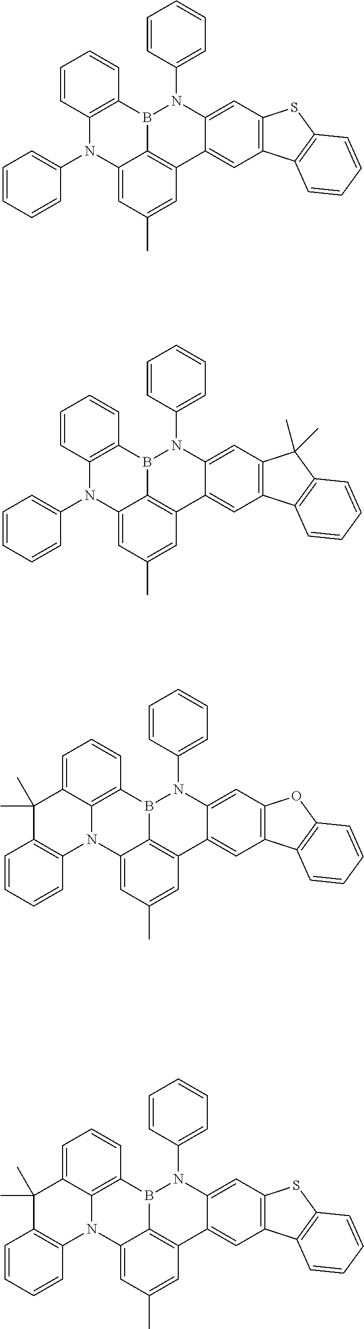 [SMILES: Cc1cc2c3c(c1)N(c1ccccc1)c1ccccc1B3N(c1ccccc1)c1cc3sc4ccccc4c3cc1-2 ; Cc1cc2c3c(c1)N(c1ccccc1)c1ccccc1B3N(c1ccccc1)c1cc3c(cc1-2)-c1ccccc1C3(C)C ; Cc1cc2c3c(c1)N1c4ccccc4C(C)(C)c4cccc(c41)B3N(c1ccccc1)c1cc3oc4ccccc4c3cc1-2 ; Cc1cc2c3c(c1)N1c4ccccc4C(C)(C)c4cccc(c41)B3N(c1ccccc1)c1cc3sc4ccccc4c3cc1-2]

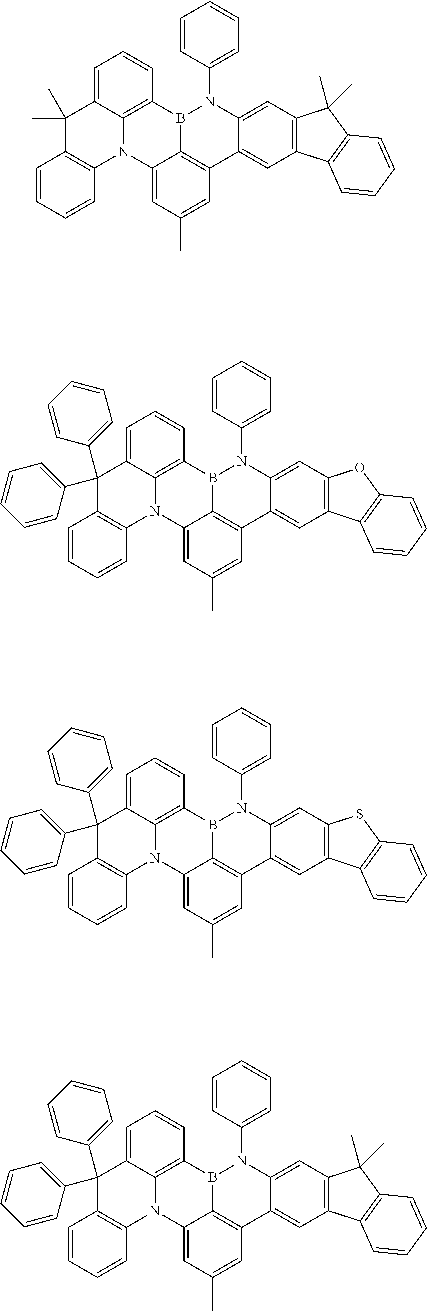 [SMILES: Cc1cc2c3c(c1)N1c4ccccc4C(C)(C)c4cccc(c41)B3N(c1ccccc1)c1cc3c(cc1-2)-c1ccccc1C3(C)C ; Cc1cc2c3c(c1)N1c4ccccc4C(c4ccccc4)(c4ccccc4)c4cccc(c41)B3N(c1ccccc1)c1cc3oc4ccccc4c3cc1-2 ; Cc1cc2c3c(c1)N1c4ccccc4C(c4ccccc4)(c4ccccc4)c4cccc(c41)B3N(c1ccccc1)c1cc3sc4ccccc4c3cc1-2 ; Cc1cc2c3c(c1)N1c4ccccc4C(c4ccccc4)(c4ccccc4)c4cccc(c41)B3N(c1ccccc1)c1cc3c(cc1-2)-c1ccccc1C3(C)C]

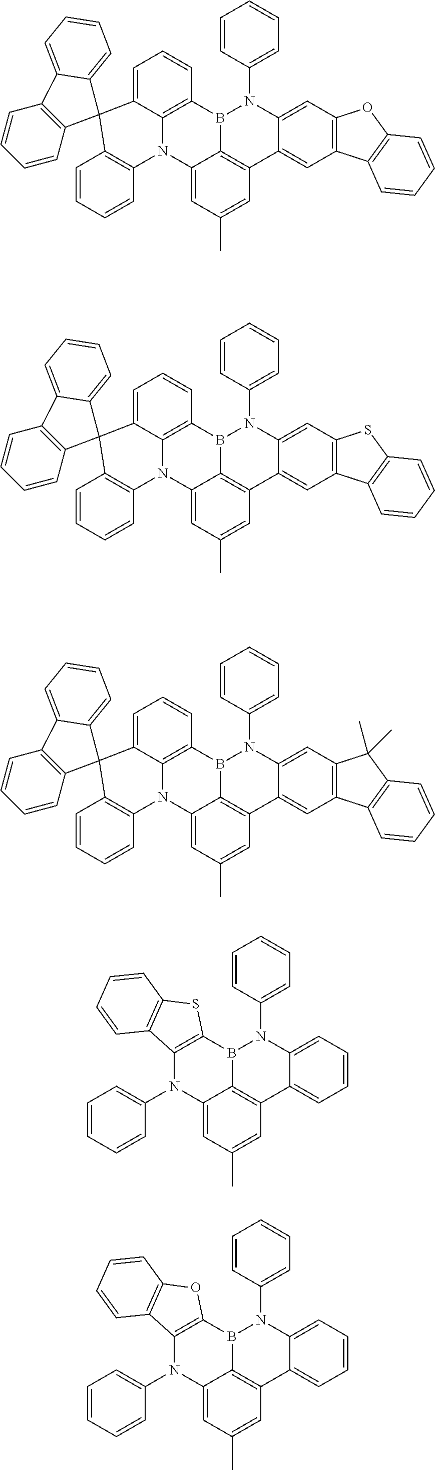

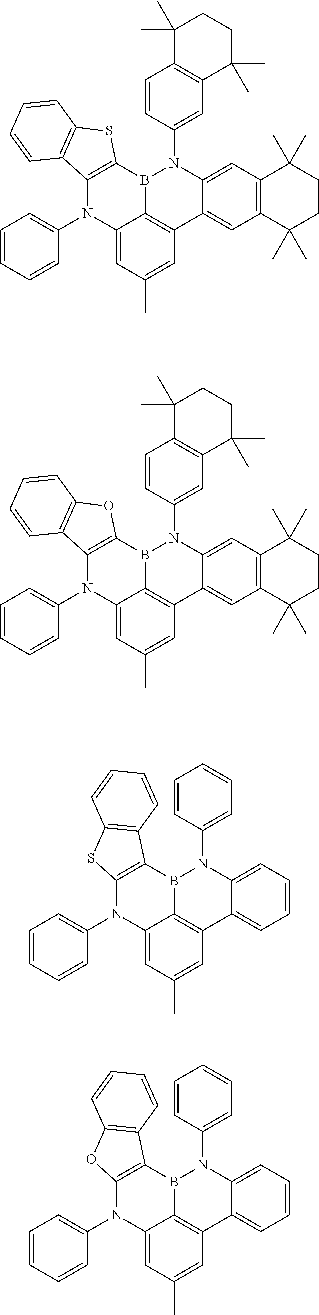 [SMILES: Cc1cc2c3c(c1)N(c1ccccc1)c1c(sc4ccccc14)B3N(c1ccc3c(c1)C(C)(C)CCC3(C)C)c1cc3c(cc1-2)C(C)(C)CCC3(C)C ; Cc1cc2c3c(c1)N(c1ccccc1)c1c(oc4ccccc14)B3N(c1ccc3c(c1)C(C)(C)CCC3(C)C)c1cc3c(cc1-2)C(C)(C)CCC3(C)C ; Cc1cc2c3c(c1)N(c1ccccc1)c1sc4ccccc4c1B3N(c1ccccc1)c1ccccc1-2 ; Cc1cc2c3c(c1)N(c1ccccc1)c1oc4ccccc4c1B3N(c1ccccc1)c1ccccc1-2]

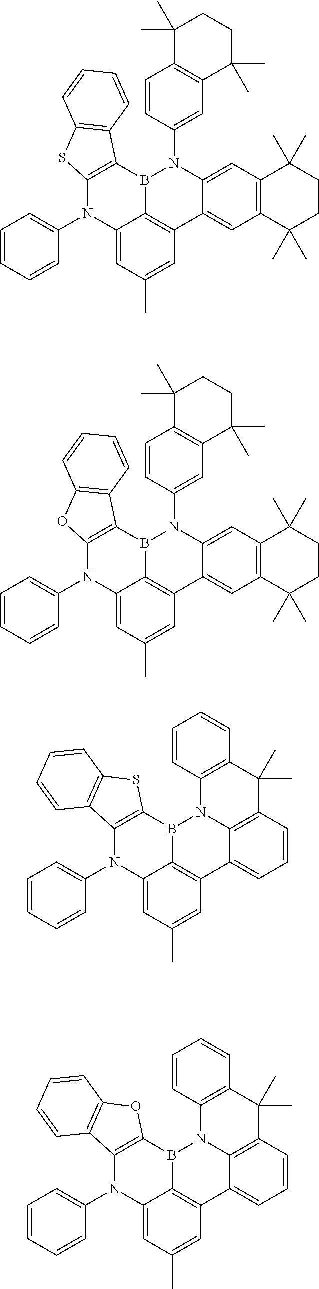 [SMILES: Cc1cc2c3c(c1)N(c1ccccc1)c1sc4ccccc4c1B3N(c1ccc3c(c1)C(C)(C)CCC3(C)C)c1cc3c(cc1-2)C(C)(C)CCC3(C)C ; Cc1cc2c3c(c1)N(c1ccccc1)c1oc4ccccc4c1B3N(c1ccc3c(c1)C(C)(C)CCC3(C)C)c1cc3c(cc1-2)C(C)(C)CCC3(C)C ; Cc1cc2c3c(c1)N(c1ccccc1)c1c(sc4ccccc14)B3N1c3ccccc3C(C)(C)c3cccc-2c31 ; Cc1cc2c3c(c1)N(c1ccccc1)c1c(oc4ccccc14)B3N1c3ccccc3C(C)(C)c3cccc-2c31]

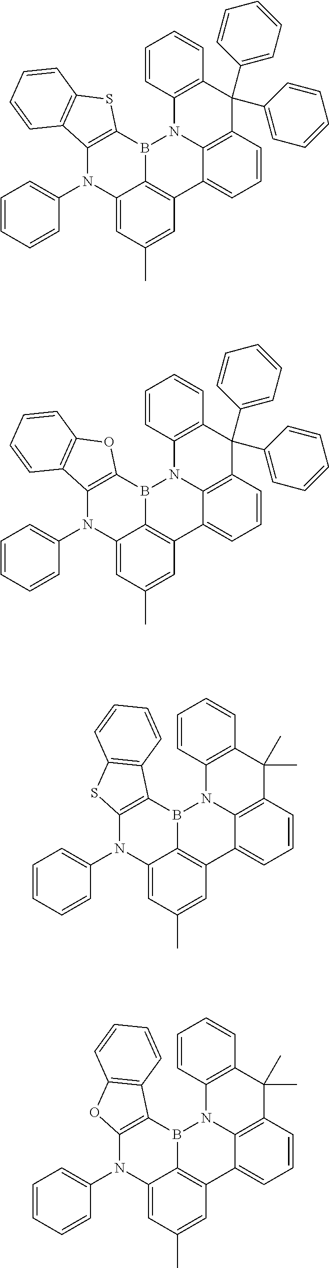 [SMILES: Cc1cc2c3c(c1)N(c1ccccc1)c1c(sc4ccccc14)B3N1c3ccccc3C(c3ccccc3)(c3ccccc3)c3cccc-2c31 ; Cc1cc2c3c(c1)N(c1ccccc1)c1c(oc4ccccc14)B3N1c3ccccc3C(c3ccccc3)(c3ccccc3)c3cccc-2c31 ; Cc1cc2c3c(c1)N(c1ccccc1)c1sc4ccccc4c1B3N1c3ccccc3C(C)(C)c3cccc-2c31 ; Cc1cc2c3c(c1)N(c1ccccc1)c1oc4ccccc4c1B3N1c3ccccc3C(C)(C)c3cccc-2c31]

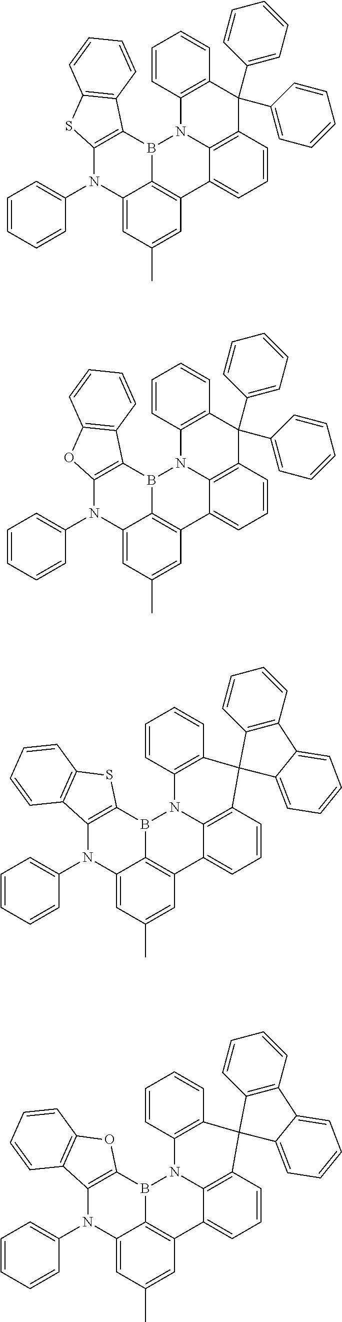 [SMILES: Cc1cc2c3c(c1)N(c1ccccc1)c1sc4ccccc4c1B3N1c3ccccc3C(c3ccccc3)(c3ccccc3)c3cccc-2c31 ; Cc1cc2c3c(c1)N(c1ccccc1)c1oc4ccccc4c1B3N1c3ccccc3C(c3ccccc3)(c3ccccc3)c3cccc-2c31 ; Cc1cc2c3c(c1)N(c1ccccc1)c1c(sc4ccccc14)B3N1c3ccccc3C3(c4ccccc4-c4ccccc43)c3cccc-2c31 ; Cc1cc2c3c(c1)N(c1ccccc1)c1c(oc4ccccc14)B3N1c3ccccc3C3(c4ccccc4-c4ccccc43)c3cccc-2c31]

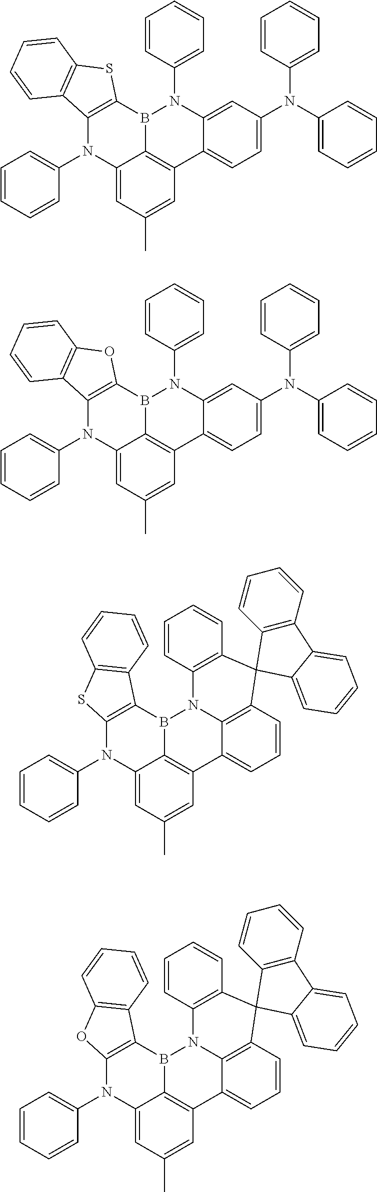

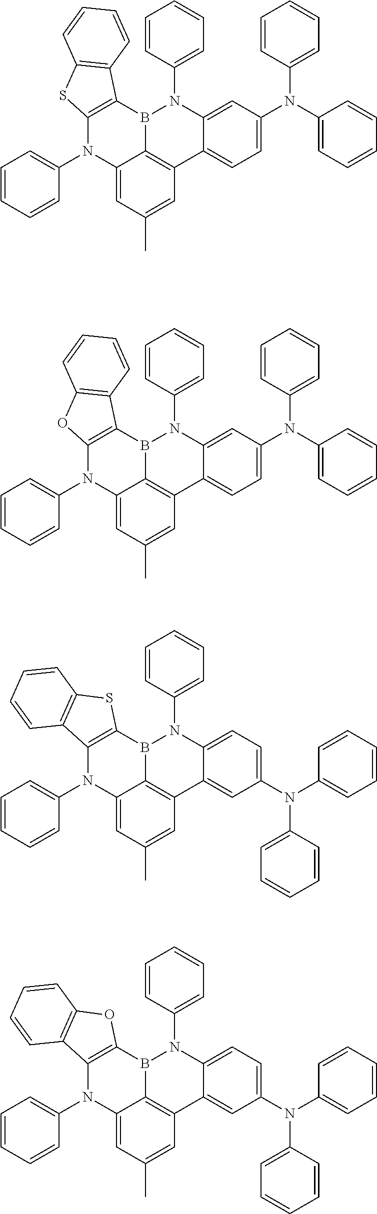 [SMILES: Cc1cc2c3c(c1)N(c1ccccc1)c1sc4ccccc4c1B3N(c1ccccc1)c1cc(N(c3ccccc3)c3ccccc3)ccc1-2 ; Cc1cc2c3c(c1)N(c1ccccc1)c1oc4ccccc4c1B3N(c1ccccc1)c1cc(N(c3ccccc3)c3ccccc3)ccc1-2 ; Cc1cc2c3c(c1)N(c1ccccc1)c1c(sc4ccccc14)B3N(c1ccccc1)c1ccc(N(c3ccccc3)c3ccccc3)cc1-2 ; Cc1cc2c3c(c1)N(c1ccccc1)c1c(oc4ccccc14)B3N(c1ccccc1)c1ccc(N(c3ccccc3)c3ccccc3)cc1-2]

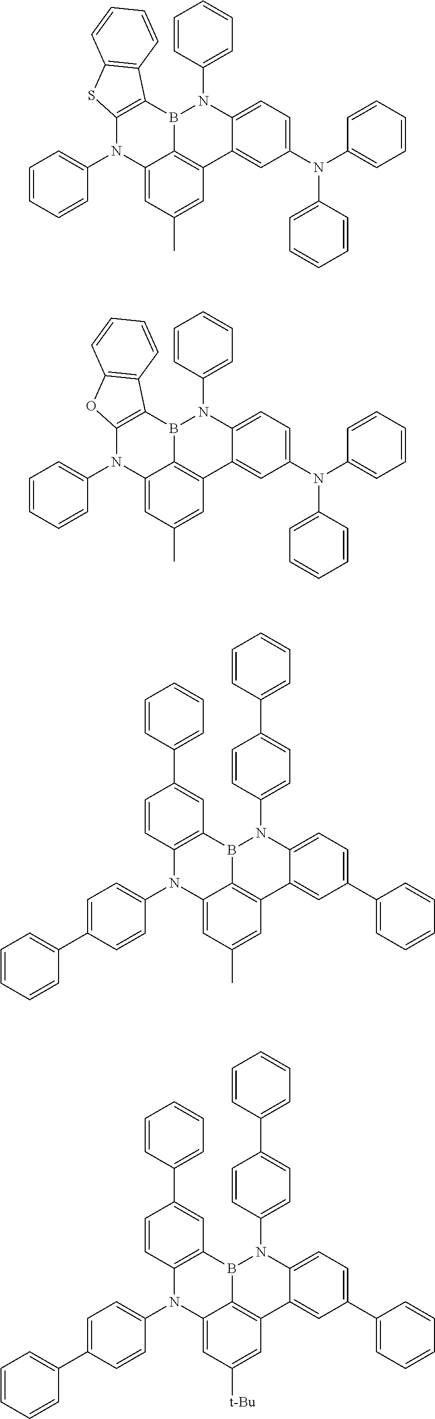 [SMILES: Cc1cc2c3c(c1)N(c1ccccc1)c1sc4ccccc4c1B3N(c1ccccc1)c1ccc(N(c3ccccc3)c3ccccc3)cc1-2 ; Cc1cc2c3c(c1)N(c1ccccc1)c1oc4ccccc4c1B3N(c1ccccc1)c1ccc(N(c3ccccc3)c3ccccc3)cc1-2 ; Cc1cc2c3c(c1)N(c1ccc(-c4ccccc4)cc1)c1ccc(-c4ccccc4)cc1B3N(c1ccc(-c3ccccc3)cc1)c1ccc(-c3ccccc3)cc1-2 ; CC(C)(C)c1cc2c3c(c1)N(c1ccc(-c4ccccc4)cc1)c1ccc(-c4ccccc4)cc1B3N(c1ccc(-c3ccccc3)cc1)c1ccc(-c3ccccc3)cc1-2]

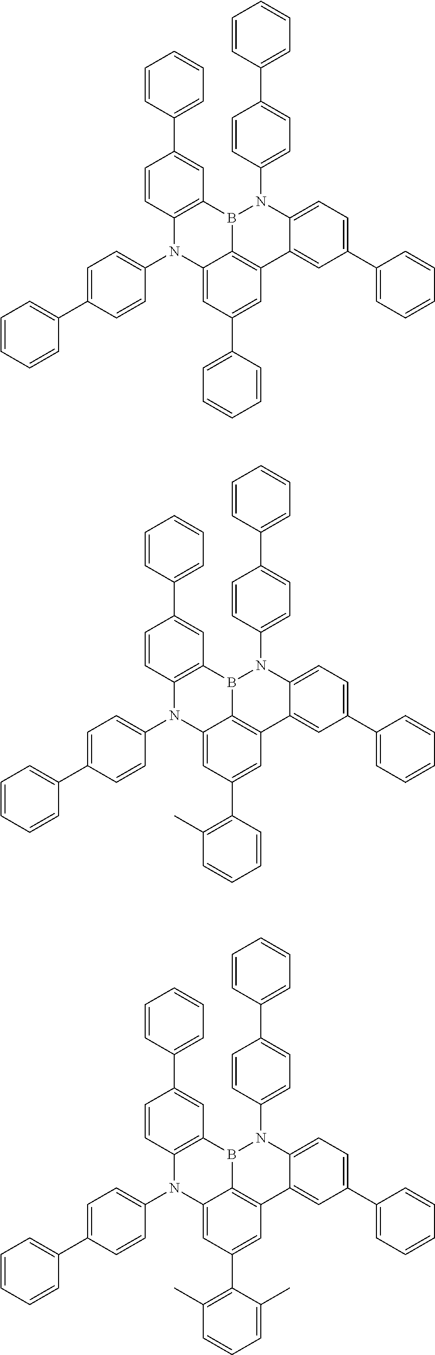 [SMILES: c1ccc(-c2ccc(N3B4c5cc(-c6ccccc6)ccc5N(c5ccc(-c6ccccc6)cc5)c5cc(-c6ccccc6)cc(c54)-c4cc(-c5ccccc5)ccc43)cc2)cc1 ; Cc1ccccc1-c1cc2c3c(c1)N(c1ccc(-c4ccccc4)cc1)c1ccc(-c4ccccc4)cc1B3N(c1ccc(-c3ccccc3)cc1)c1ccc(-c3ccccc3)cc1-2 ; Cc1cccc(C)c1-c1cc2c3c(c1)N(c1ccc(-c4ccccc4)cc1)c1ccc(-c4ccccc4)cc1B3N(c1ccc(-c3ccccc3)cc1)c1ccc(-c3ccccc3)cc1-2]

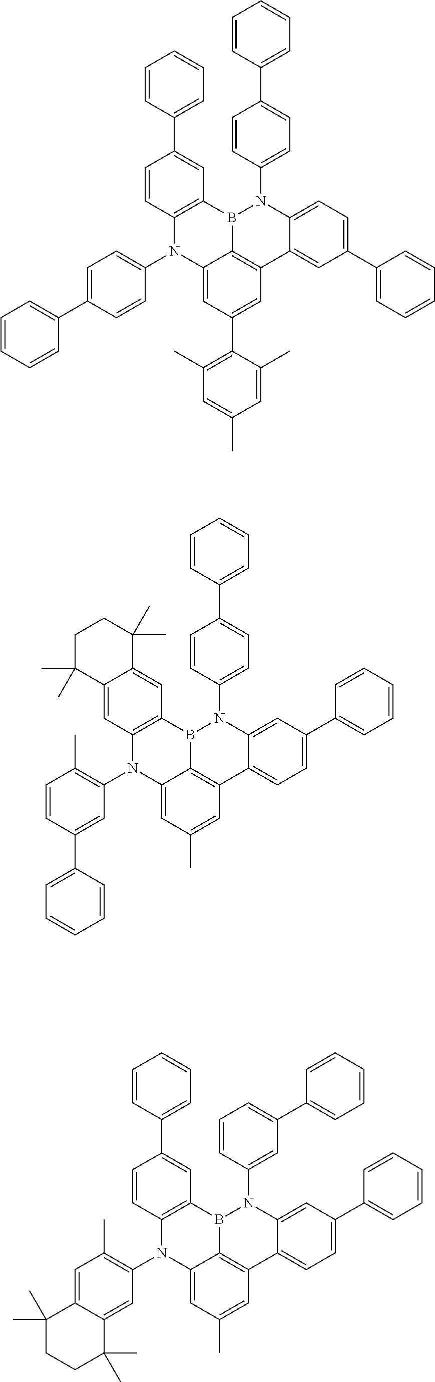 [SMILES: Cc1cc(C)c(-c2cc3c4c(c2)N(c2ccc(-c5ccccc5)cc2)c2ccc(-c5ccccc5)cc2B4N(c2ccc(-c4ccccc4)cc2)c2ccc(-c4ccccc4)cc2-3)c(C)c1 ; Cc1cc2c3c(c1)N(c1cc(-c4ccccc4)ccc1C)c1cc4c(cc1B3N(c1ccc(-c3ccccc3)cc1)c1cc(-c3ccccc3)ccc1-2)C(C)(C)CCC4(C)C ; Cc1cc2c3c(c1)N(c1cc4c(cc1C)C(C)(C)CCC4(C)C)c1ccc(-c4ccccc4)cc1B3N(c1cccc(-c3ccccc3)c1)c1cc(-c3ccccc3)ccc1-2]

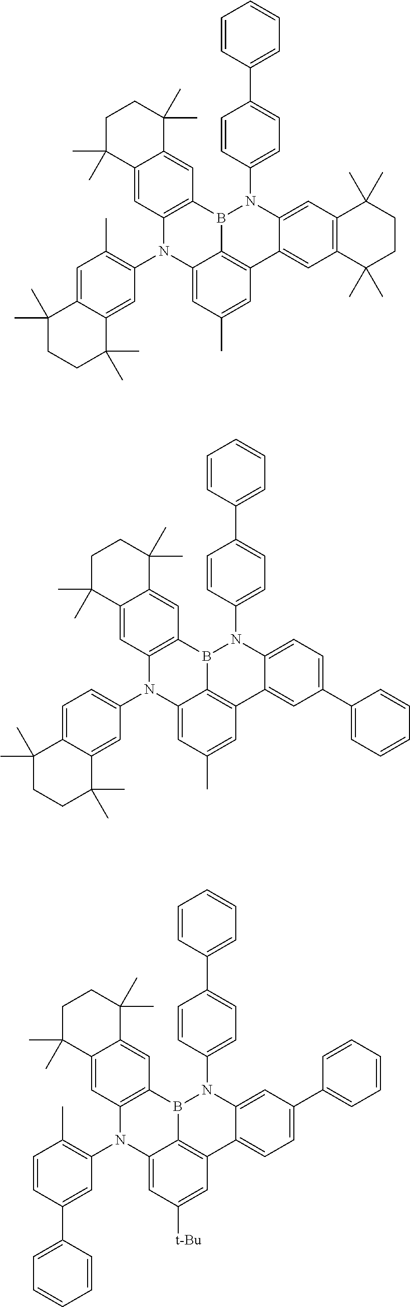 [SMILES: Cc1cc2c3c(c1)N(c1cc4c(cc1C)C(C)(C)CCC4(C)C)c1cc4c(cc1B3N(c1ccc(-c3ccccc3)cc1)c1cc3c(cc1-2)C(C)(C)CCC3(C)C)C(C)(C)CCC4(C)C ; Cc1cc2c3c(c1)N(c1ccc4c(c1)C(C)(C)CCC4(C)C)c1cc4c(cc1B3N(c1ccc(-c3ccccc3)cc1)c1ccc(-c3ccccc3)cc1-2)C(C)(C)CCC4(C)C ; Cc1ccc(-c2ccccc2)cc1N1c2cc3c(cc2B2c4c(cc(C(C)(C)C)cc41)-c1ccc(-c4ccccc4)cc1N2c1ccc(-c2ccccc2)cc1)C(C)(C)CCC3(C)C]

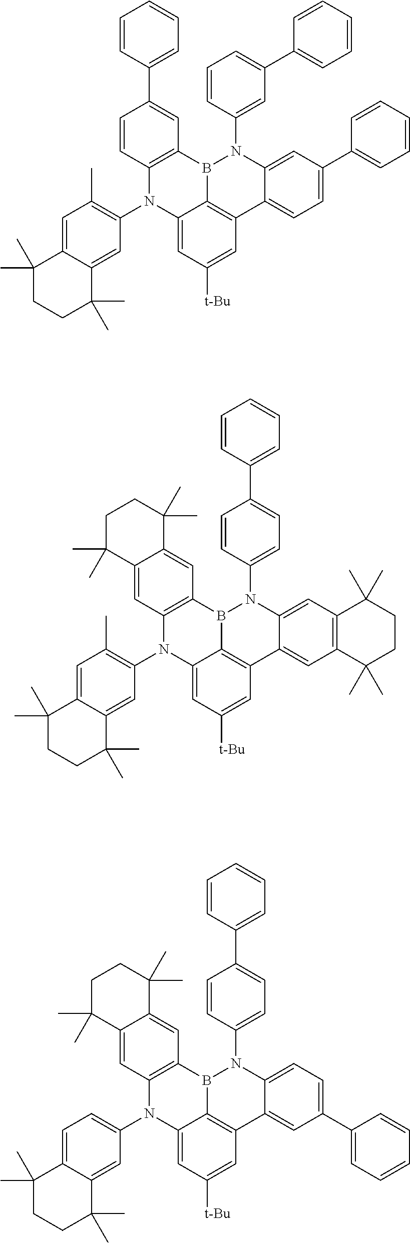 [SMILES: Cc1cc2c(cc1N1c3ccc(-c4ccccc4)cc3B3c4c(cc(C(C)(C)C)cc41)-c1ccc(-c4ccccc4)cc1N3c1cccc(-c3ccccc3)c1)C(C)(C)CCC2(C)C ; Cc1cc2c(cc1N1c3cc4c(cc3B3c5c(cc(C(C)(C)C)cc51)-c1cc5c(cc1N3c1ccc(-c3ccccc3)cc1)C(C)(C)CCC5(C)C)C(C)(C)CCC4(C)C)C(C)(C)CCC2(C)C ; CC(C)(C)c1cc2c3c(c1)N(c1ccc4c(c1)C(C)(C)CCC4(C)C)c1cc4c(cc1B3N(c1ccc(-c3ccccc3)cc1)c1ccc(-c3ccccc3)cc1-2)C(C)(C)CCC4(C)C]

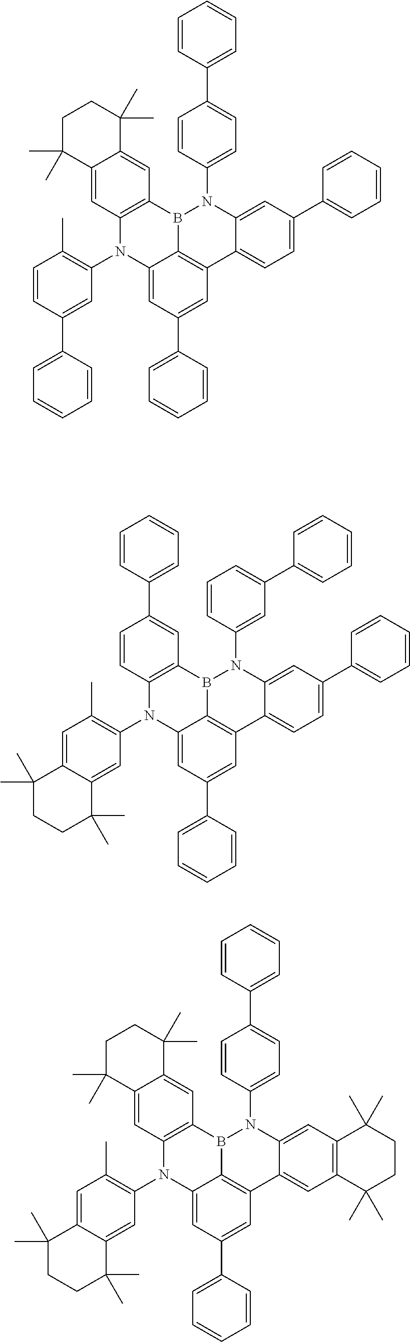 [SMILES: Cc1ccc(-c2ccccc2)cc1N1c2cc3c(cc2B2c4c(cc(-c5ccccc5)cc41)-c1ccc(-c4ccccc4)cc1N2c1ccc(-c2ccccc2)cc1)C(C)(C)CCC3(C)C ; Cc1cc2c(cc1N1c3ccc(-c4ccccc4)cc3B3c4c(cc(-c5ccccc5)cc41)-c1ccc(-c4ccccc4)cc1N3c1cccc(-c3ccccc3)c1)C(C)(C)CCC2(C)C ; Cc1cc2c(cc1N1c3cc4c(cc3B3c5c(cc(-c6ccccc6)cc51)-c1cc5c(cc1N3c1ccc(-c3ccccc3)cc1)C(C)(C)CCC5(C)C)C(C)(C)CCC4(C)C)C(C)(C)CCC2(C)C]

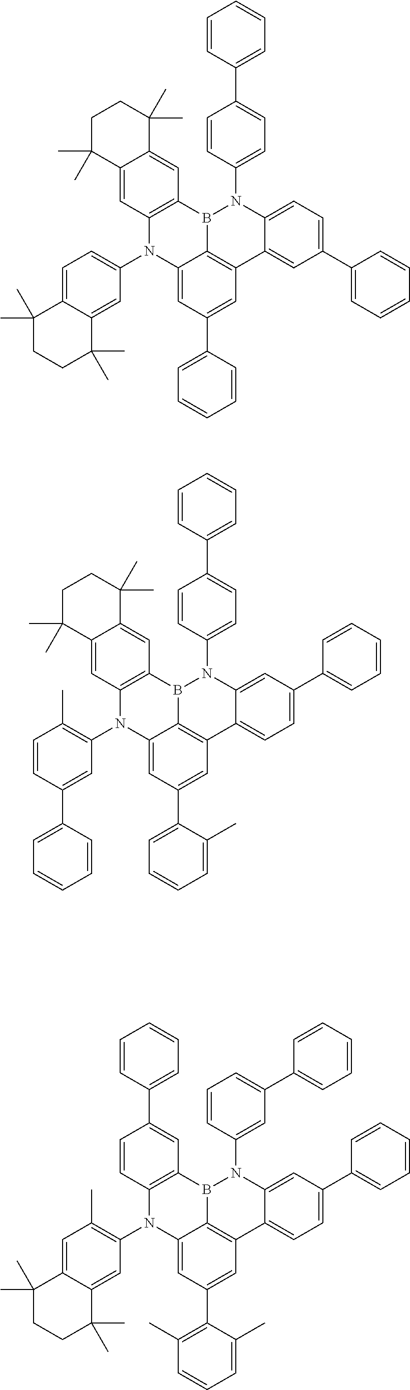 [SMILES: CC1(C)CCC(C)(C)c2cc(N3c4cc5c(cc4B4c6c(cc(-c7ccccc7)cc63)-c3cc(-c6ccccc6)ccc3N4c3ccc(-c4ccccc4)cc3)C(C)(C)CCC5(C)C)ccc21 ; Cc1ccccc1-c1cc2c3c(c1)N(c1cc(-c4ccccc4)ccc1C)c1cc4c(cc1B3N(c1ccc(-c3ccccc3)cc1)c1cc(-c3ccccc3)ccc1-2)C(C)(C)CCC4(C)C ; Cc1cc2c(cc1N1c3ccc(-c4ccccc4)cc3B3c4c(cc(-c5c(C)cccc5C)cc41)-c1ccc(-c4ccccc4)cc1N3c1cccc(-c3ccccc3)c1)C(C)(C)CCC2(C)C]

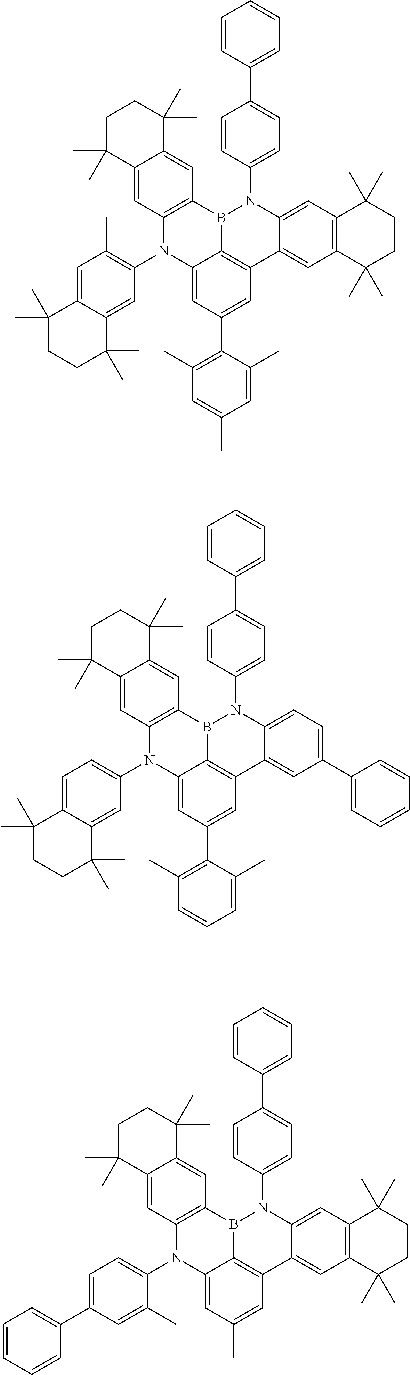 [SMILES: Cc1cc(C)c(-c2cc3c4c(c2)N(c2cc5c(cc2C)C(C)(C)CCC5(C)C)c2cc5c(cc2B4N(c2ccc(-c4ccccc4)cc2)c2cc4c(cc2-3)C(C)(C)CCC4(C)C)C(C)(C)CCC5(C)C)c(C)c1 ; Cc1cccc(C)c1-c1cc2c3c(c1)N(c1ccc4c(c1)C(C)(C)CCC4(C)C)c1cc4c(cc1B3N(c1ccc(-c3ccccc3)cc1)c1ccc(-c3ccccc3)cc1-2)C(C)(C)CCC4(C)C ; Cc1cc2c3c(c1)N(c1ccc(-c4ccccc4)cc1C)c1cc4c(cc1B3N(c1ccc(-c3ccccc3)cc1)c1cc3c(cc1-2)C(C)(C)CCC3(C)C)C(C)(C)CCC4(C)C]

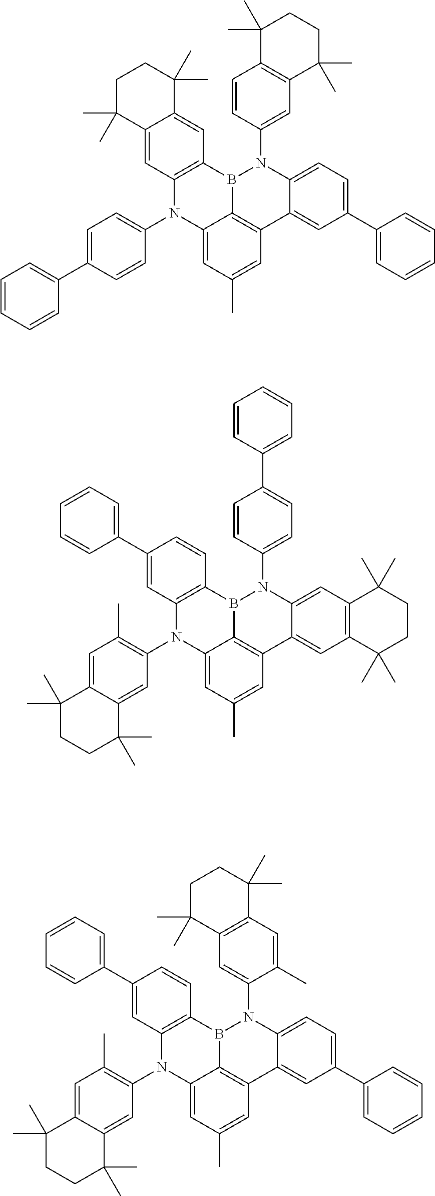 [SMILES: Cc1cc2c3c(c1)N(c1ccc(-c4ccccc4)cc1)c1cc4c(cc1B3N(c1ccc3c(c1)C(C)(C)CCC3(C)C)c1ccc(-c3ccccc3)cc1-2)C(C)(C)CCC4(C)C ; Cc1cc2c3c(c1)N(c1cc4c(cc1C)C(C)(C)CCC4(C)C)c1cc(-c4ccccc4)ccc1B3N(c1ccc(-c3ccccc3)cc1)c1cc3c(cc1-2)C(C)(C)CCC3(C)C ; Cc1cc2c3c(c1)N(c1cc4c(cc1C)C(C)(C)CCC4(C)C)c1cc(-c4ccccc4)ccc1B3N(c1cc3c(cc1C)C(C)(C)CCC3(C)C)c1ccc(-c3ccccc3)cc1-2]

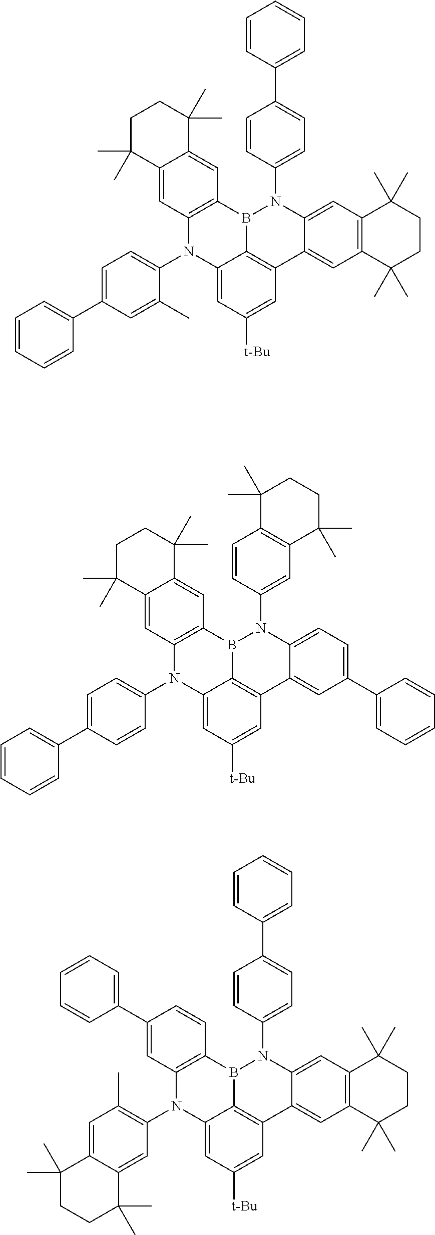 [SMILES: Cc1cc(-c2ccccc2)ccc1N1c2cc3c(cc2B2c4c(cc(C(C)(C)C)cc41)-c1cc4c(cc1N2c1ccc(-c2ccccc2)cc1)C(C)(C)CCC4(C)C)C(C)(C)CCC3(C)C ; CC(C)(C)c1cc2c3c(c1)N(c1ccc(-c4ccccc4)cc1)c1cc4c(cc1B3N(c1ccc3c(c1)C(C)(C)CCC3(C)C)c1ccc(-c3ccccc3)cc1-2)C(C)(C)CCC4(C)C ; Cc1cc2c(cc1N1c3cc(-c4ccccc4)ccc3B3c4c(cc(C(C)(C)C)cc41)-c1cc4c(cc1N3c1ccc(-c3ccccc3)cc1)C(C)(C)CCC4(C)C)C(C)(C)CCC2(C)C]

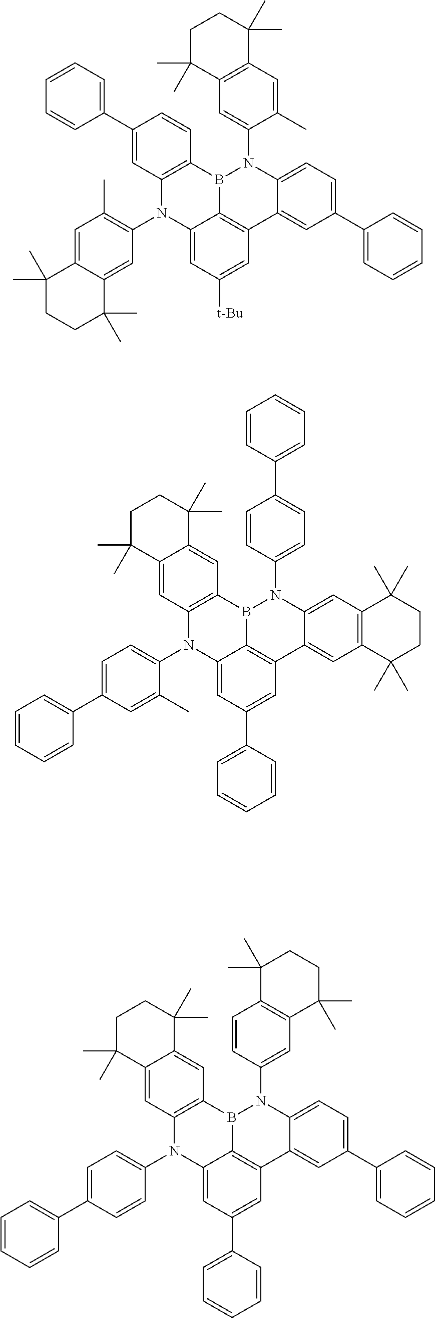 [SMILES: Cc1cc2c(cc1N1B3c4ccc(-c5ccccc5)cc4N(c4cc5c(cc4C)C(C)(C)CCC5(C)C)c4cc(C(C)(C)C)cc(c43)-c3cc(-c4ccccc4)ccc31)C(C)(C)CCC2(C)C ; Cc1cc(-c2ccccc2)ccc1N1c2cc3c(cc2B2c4c(cc(-c5ccccc5)cc41)-c1cc4c(cc1N2c1ccc(-c2ccccc2)cc1)C(C)(C)CCC4(C)C)C(C)(C)CCC3(C)C ; CC1(C)CCC(C)(C)c2cc(N3B4c5cc6c(cc5N(c5ccc(-c7ccccc7)cc5)c5cc(-c7ccccc7)cc(c54)-c4cc(-c5ccccc5)ccc43)C(C)(C)CCC6(C)C)ccc21]

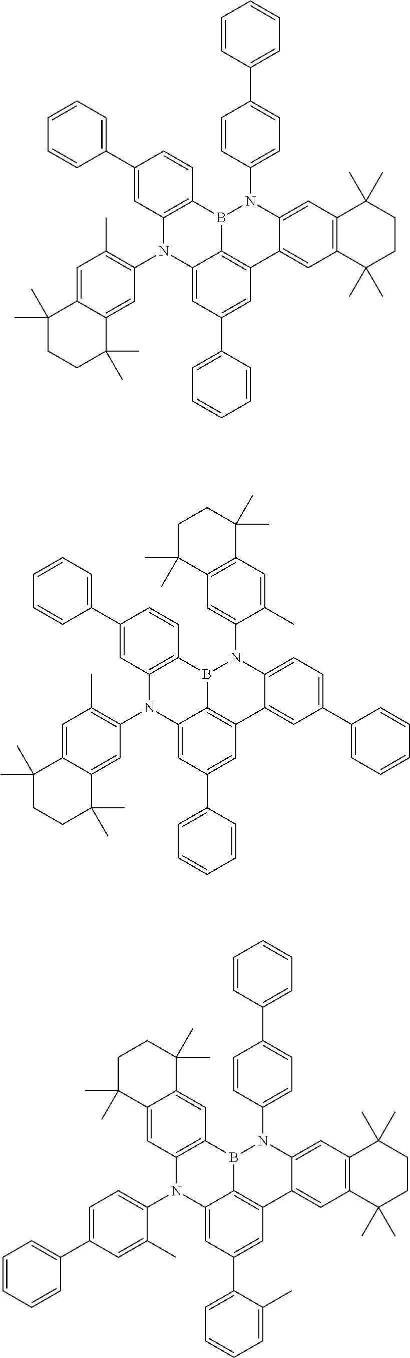 [SMILES: Cc1cc2c(cc1N1c3cc(-c4ccccc4)ccc3B3c4c(cc(-c5ccccc5)cc41)-c1cc4c(cc1N3c1ccc(-c3ccccc3)cc1)C(C)(C)CCC4(C)C)C(C)(C)CCC2(C)C ; Cc1cc2c(cc1N1B3c4ccc(-c5ccccc5)cc4N(c4cc5c(cc4C)C(C)(C)CCC5(C)C)c4cc(-c5ccccc5)cc(c43)-c3cc(-c4ccccc4)ccc31)C(C)(C)CCC2(C)C ; Cc1ccccc1-c1cc2c3c(c1)N(c1ccc(-c4ccccc4)cc1C)c1cc4c(cc1B3N(c1ccc(-c3ccccc3)cc1)c1cc3c(cc1-2)C(C)(C)CCC3(C)C)C(C)(C)CCC4(C)C]

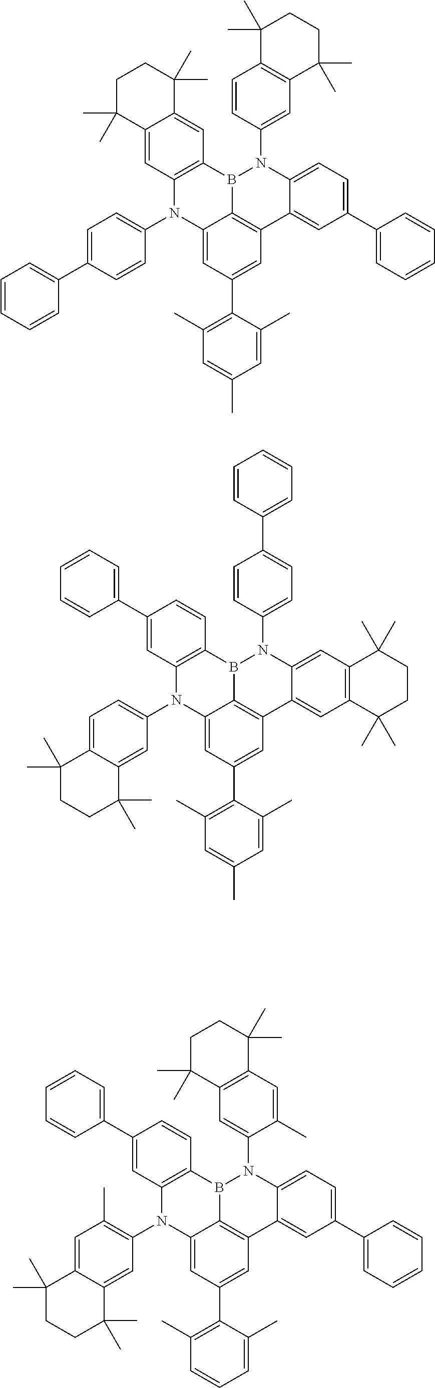 [SMILES: Cc1cc(C)c(-c2cc3c4c(c2)N(c2ccc(-c5ccccc5)cc2)c2cc5c(cc2B4N(c2ccc4c(c2)C(C)(C)CCC4(C)C)c2ccc(-c4ccccc4)cc2-3)C(C)(C)CCC5(C)C)c(C)c1 ; Cc1cc(C)c(-c2cc3c4c(c2)N(c2ccc5c(c2)C(C)(C)CCC5(C)C)c2cc(-c5ccccc5)ccc2B4N(c2ccc(-c4ccccc4)cc2)c2cc4c(cc2-3)C(C)(C)CCC4(C)C)c(C)c1 ; Cc1cc2c(cc1N1B3c4ccc(-c5ccccc5)cc4N(c4cc5c(cc4C)C(C)(C)CCC5(C)C)c4cc(-c5c(C)cccc5C)cc(c43)-c3cc(-c4ccccc4)ccc31)C(C)(C)CCC2(C)C]

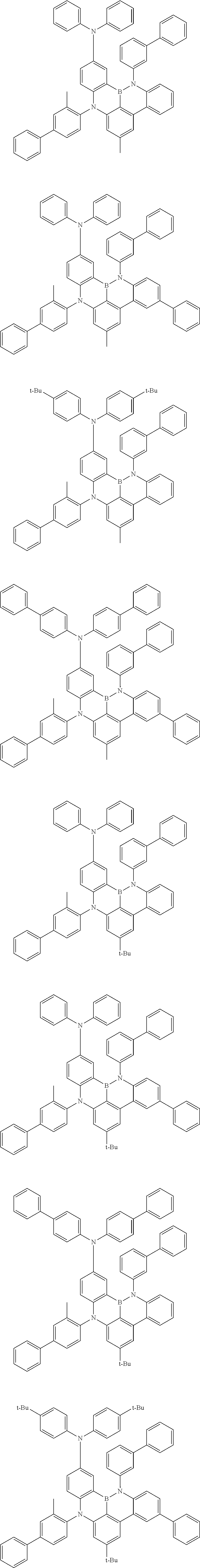

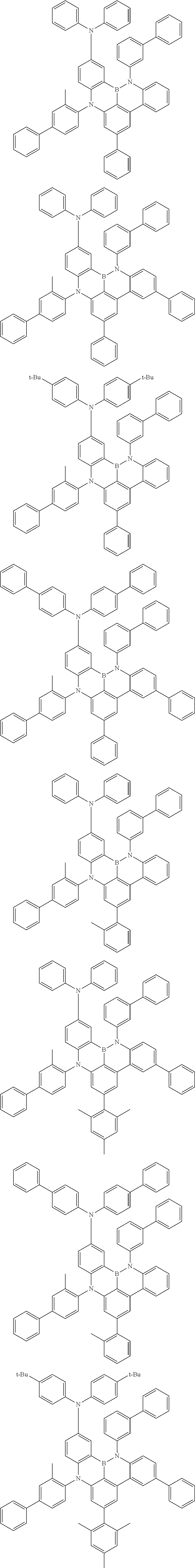

[chemical structure]

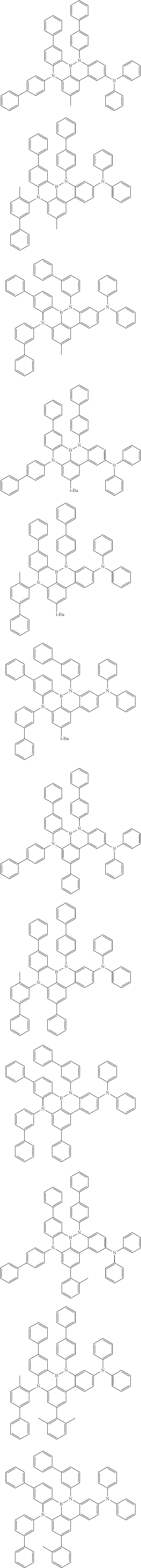

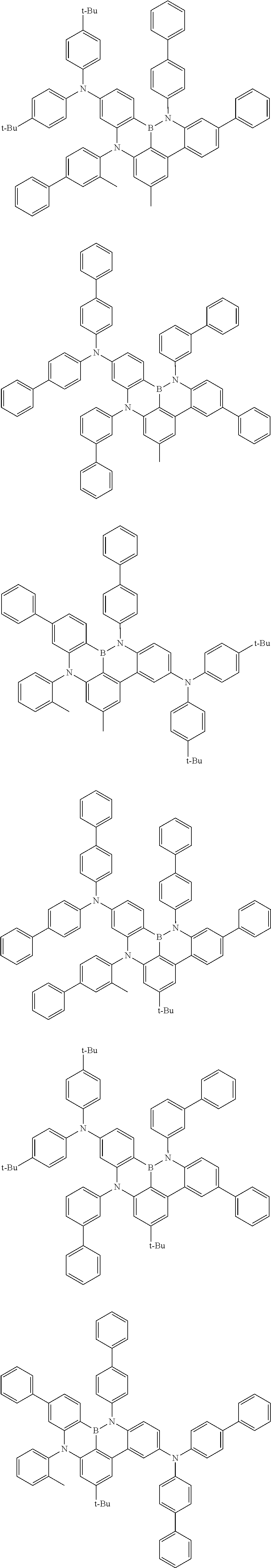

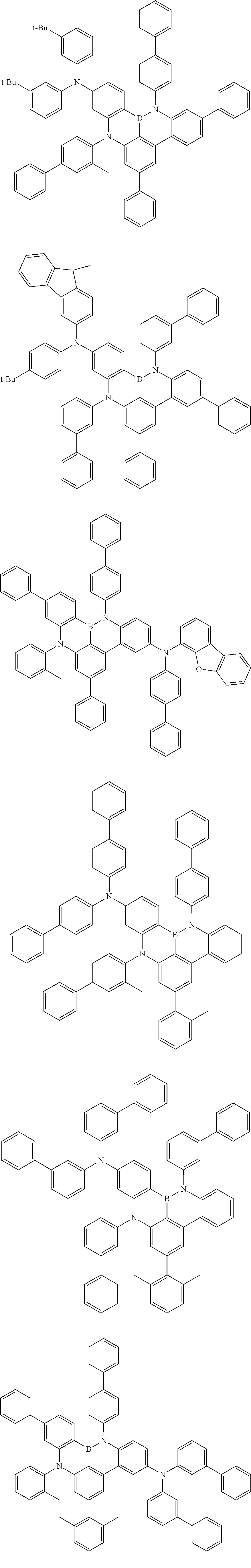

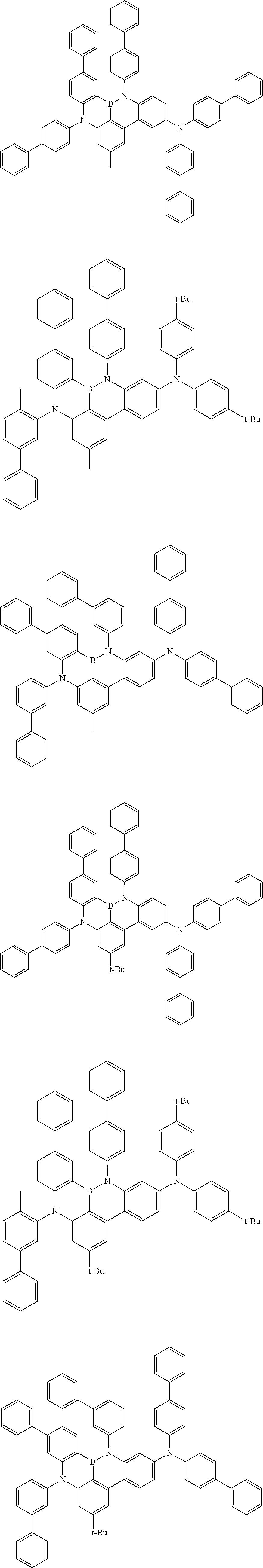

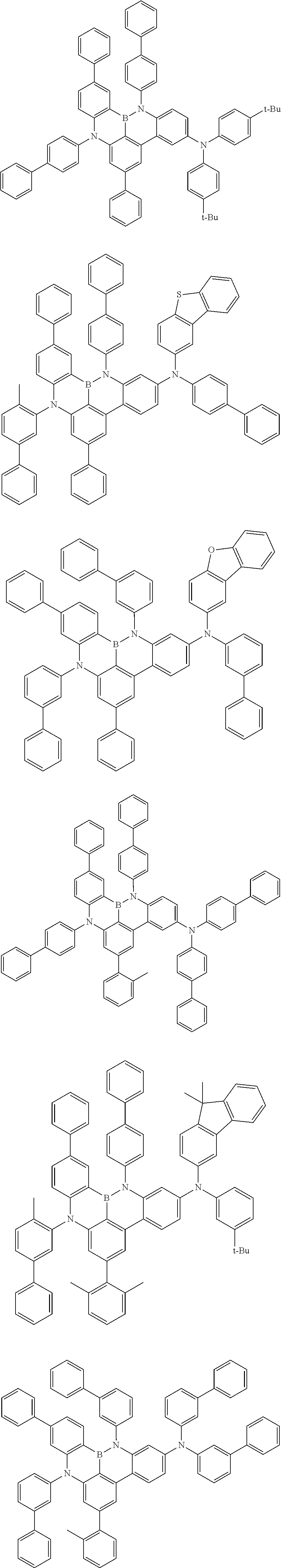

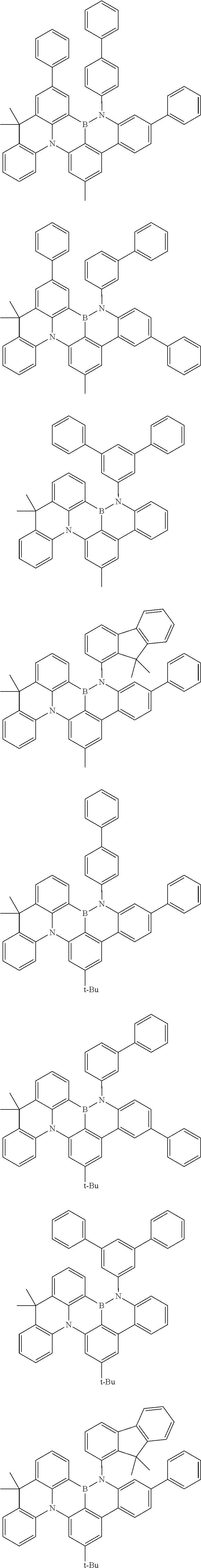

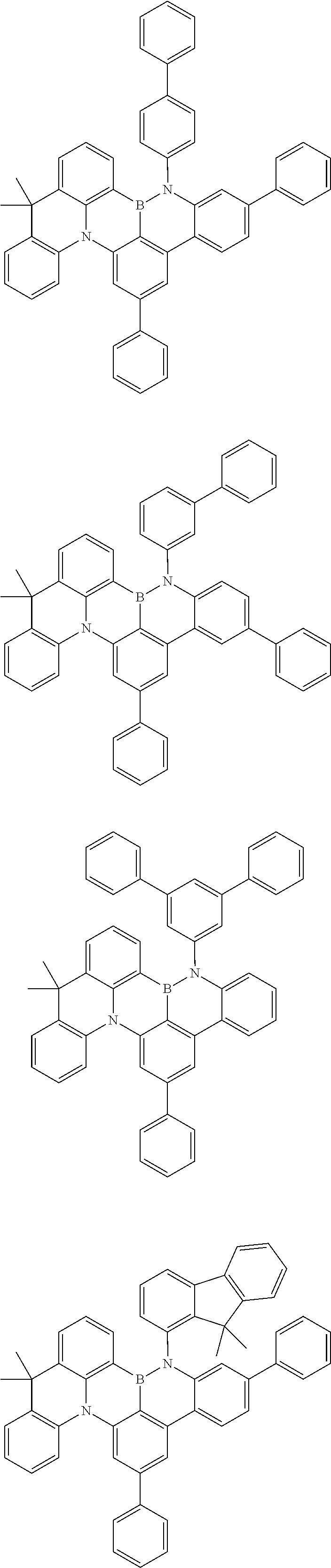 [SMILES: CC1(C)c2ccccc2N2c3cc(-c4ccccc4)cc4c3B(c3cccc1c32)N(c1ccc(-c2ccccc2)cc1)c1cc(-c2ccccc2)ccc1-4 ; CC1(C)c2ccccc2N2c3cc(-c4ccccc4)cc4c3B(c3cccc1c32)N(c1cccc(-c2ccccc2)c1)c1ccc(-c2ccccc2)cc1-4 ; CC1(C)c2ccccc2N2c3cc(-c4ccccc4)cc4c3B(c3cccc1c32)N(c1cc(-c2ccccc2)cc(-c2ccccc2)c1)c1ccccc1-4 ; CC1(C)c2ccccc2N2c3cc(-c4ccccc4)cc4c3B(c3cccc1c32)N(c1cccc2c1C(C)(C)c1ccccc1-2)c1cc(-c2ccccc2)ccc1-4]

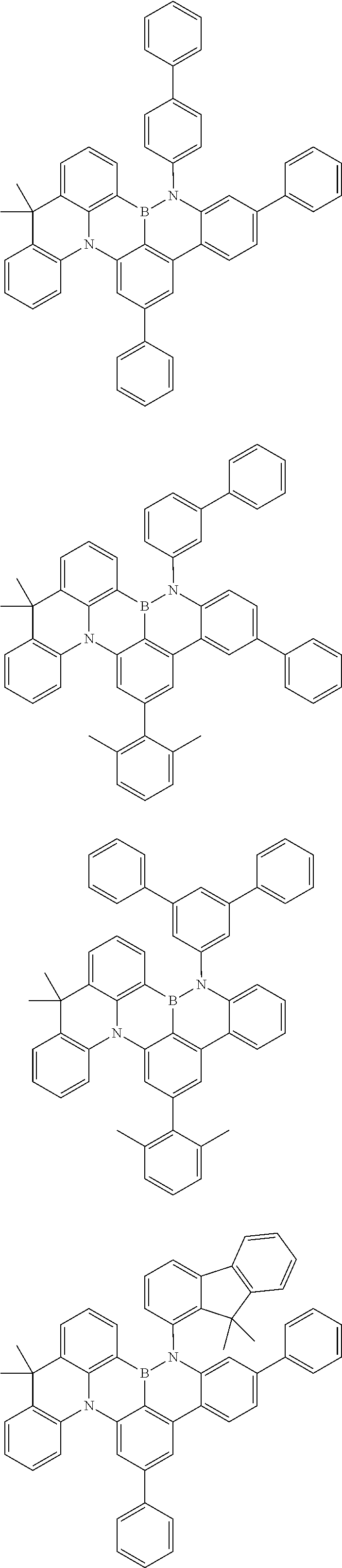 [SMILES: CC1(C)c2ccccc2N2c3cc(-c4ccccc4)cc4c3B(c3cccc1c32)N(c1ccc(-c2ccccc2)cc1)c1cc(-c2ccccc2)ccc1-4 ; Cc1cccc(C)c1-c1cc2c3c(c1)N1c4ccccc4C(C)(C)c4cccc(c41)B3N(c1cccc(-c3ccccc3)c1)c1ccc(-c3ccccc3)cc1-2 ; Cc1cccc(C)c1-c1cc2c3c(c1)N1c4ccccc4C(C)(C)c4cccc(c41)B3N(c1cc(-c3ccccc3)cc(-c3ccccc3)c1)c1ccccc1-2 ; CC1(C)c2ccccc2N2c3cc(-c4ccccc4)cc4c3B(c3cccc1c32)N(c1cccc2c1C(C)(C)c1ccccc1-2)c1cc(-c2ccccc2)ccc1-4]

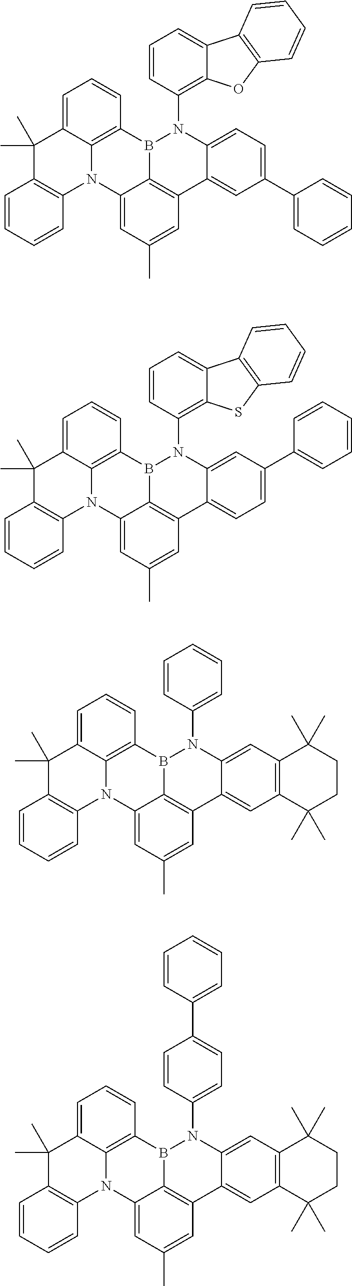 [SMILES: Cc1cc2c3c(c1)N1c4ccccc4C(C)(C)c4cccc(c41)B3N(c1cccc3c1oc1ccccc13)c1ccc(-c3ccccc3)cc1-2 ; Cc1cc2c3c(c1)N1c4ccccc4C(C)(C)c4cccc(c41)B3N(c1cccc3c1sc1ccccc13)c1cc(-c3ccccc3)ccc1-2 ; Cc1cc2c3c(c1)N1c4ccccc4C(C)(C)c4cccc(c41)B3N(c1ccccc1)c1cc3c(cc1-2)C(C)(C)CCC3(C)C ; Cc1cc2c3c(c1)N1c4ccccc4C(C)(C)c4cccc(c41)B3N(c1ccc(-c3ccccc3)cc1)c1cc3c(cc1-2)C(C)(C)CCC3(C)C]

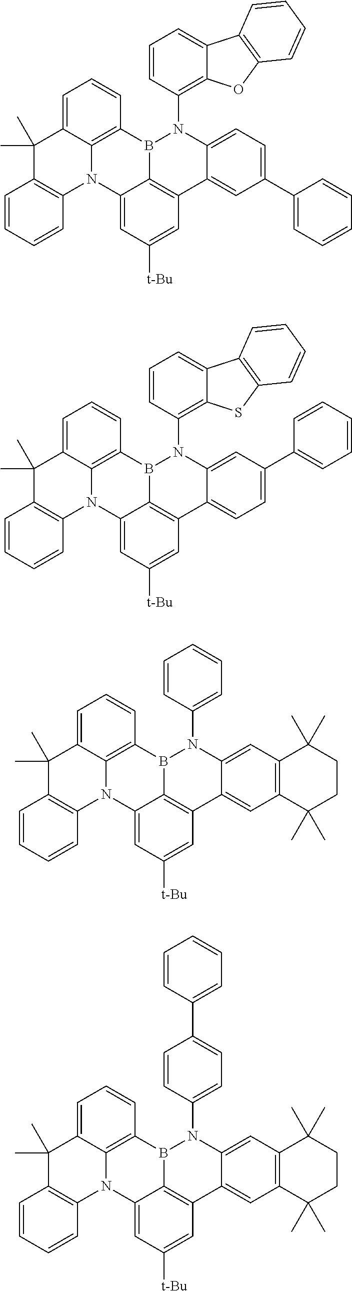 [SMILES: CC(C)(C)c1cc2c3c(c1)N1c4ccccc4C(C)(C)c4cccc(c41)B3N(c1cccc3c1oc1ccccc13)c1ccc(-c3ccccc3)cc1-2 ; CC(C)(C)c1cc2c3c(c1)N1c4ccccc4C(C)(C)c4cccc(c41)B3N(c1cccc3c1sc1ccccc13)c1cc(-c3ccccc3)ccc1-2 ; CC(C)(C)c1cc2c3c(c1)N1c4ccccc4C(C)(C)c4cccc(c41)B3N(c1ccccc1)c1cc3c(cc1-2)C(C)(C)CCC3(C)C ; CC(C)(C)c1cc2c3c(c1)N1c4ccccc4C(C)(C)c4cccc(c41)B3N(c1ccc(-c3ccccc3)cc1)c1cc3c(cc1-2)C(C)(C)CCC3(C)C]

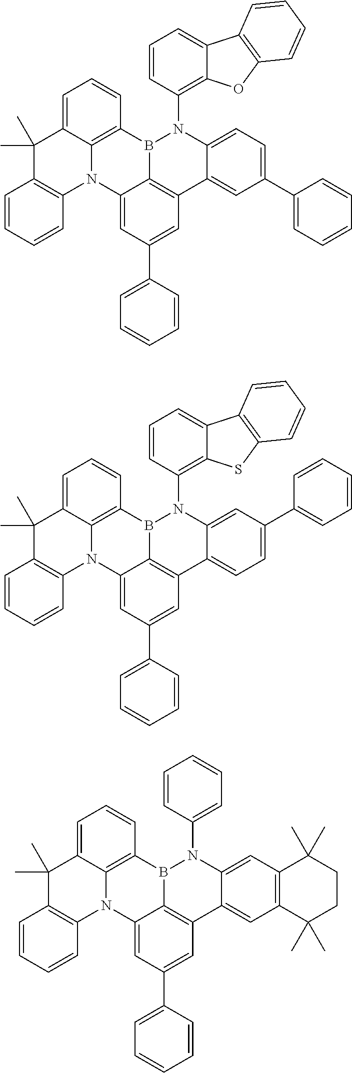 [SMILES: CC1(C)c2ccccc2N2c3cc(-c4ccccc4)cc4c3B(c3cccc1c32)N(c1cccc2c1oc1ccccc12)c1ccc(-c2ccccc2)cc1-4 ; CC1(C)c2ccccc2N2c3cc(-c4ccccc4)cc4c3B(c3cccc1c32)N(c1cccc2c1sc1ccccc12)c1cc(-c2ccccc2)ccc1-4 ; CC1(C)CCC(C)(C)c2cc3c(cc21)-c1cc(-c2ccccc2)cc2c1B(c1cccc4c1N2c1ccccc1C4(C)C)N3c1ccccc1]

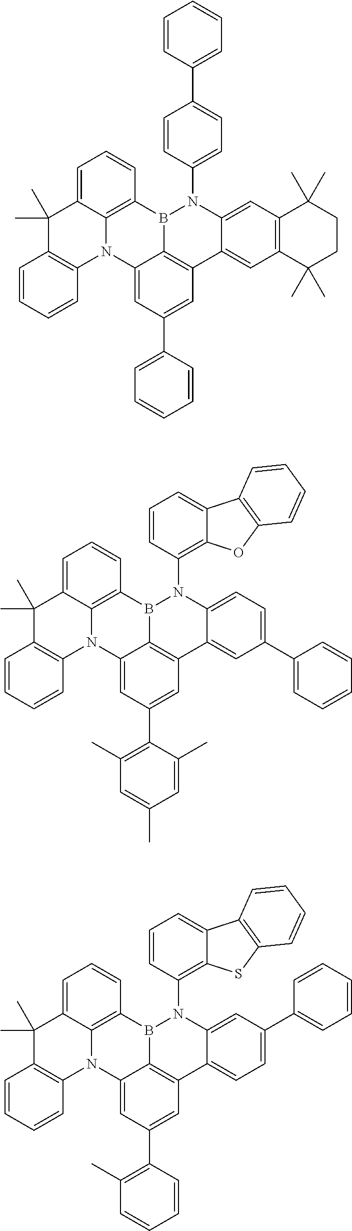 [SMILES: CC1(C)CCC(C)(C)c2cc3c(cc21)-c1cc(-c2ccccc2)cc2c1B(c1cccc4c1N2c1ccccc1C4(C)C)N3c1ccc(-c2ccccc2)cc1 ; Cc1cc(C)c(-c2cc3c4c(c2)N2c5ccccc5C(C)(C)c5cccc(c52)B4N(c2cccc4c2oc2ccccc24)c2ccc(-c4ccccc4)cc2-3)c(C)c1 ; Cc1ccccc1-c1cc2c3c(c1)N1c4ccccc4C(C)(C)c4cccc(c41)B3N(c1cccc3c1sc1ccccc13)c1cc(-c3ccccc3)ccc1-2]

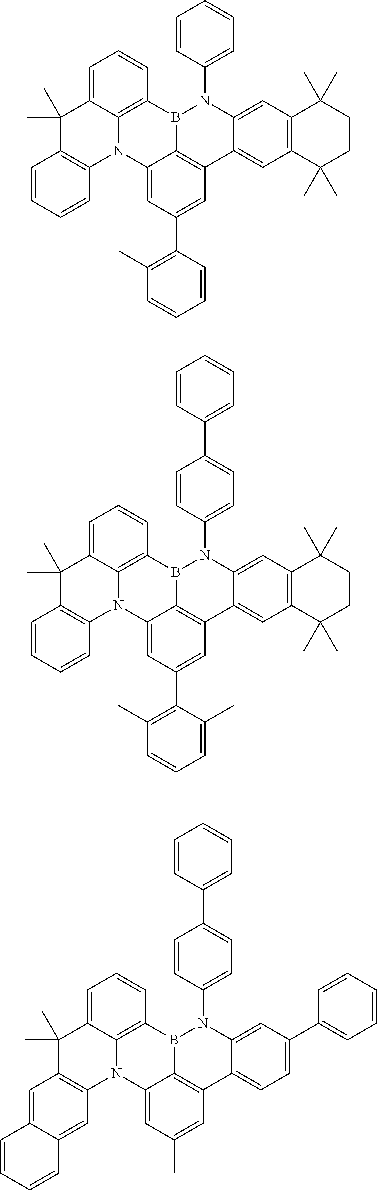 [SMILES: Cc1ccccc1-c1cc2c3c(c1)N1c4ccccc4C(C)(C)c4cccc(c41)B3N(c1ccccc1)c1cc3c(cc1-2)C(C)(C)CCC3(C)C ; Cc1cccc(C)c1-c1cc2c3c(c1)N1c4ccccc4C(C)(C)c4cccc(c41)B3N(c1ccc(-c3ccccc3)cc1)c1cc3c(cc1-2)C(C)(C)CCC3(C)C ; Cc1cc2c3c(c1)N1c4cc5ccccc5cc4C(C)(C)c4cccc(c41)B3N(c1ccc(-c3ccccc3)cc1)c1cc(-c3ccccc3)ccc1-2]

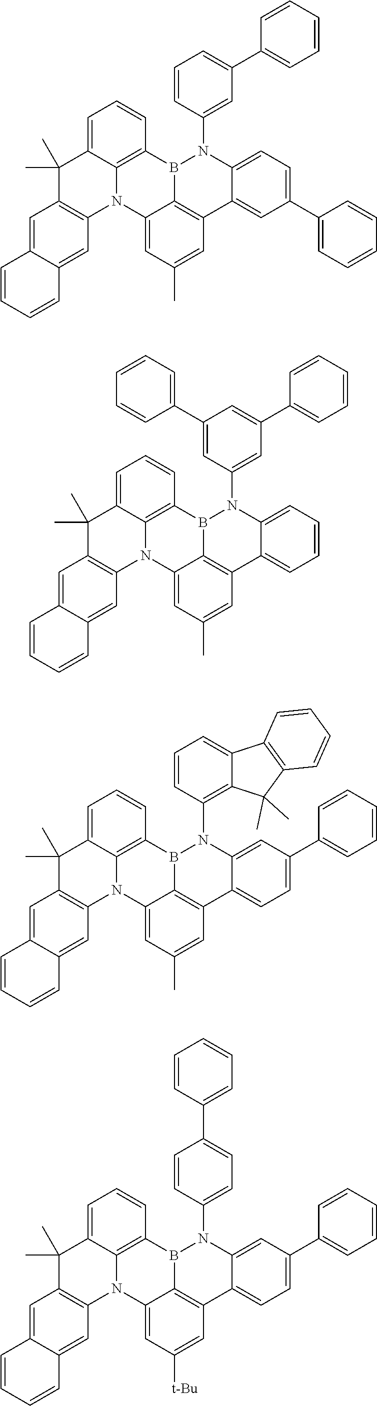 [SMILES: Cc1cc2c3c(c1)N1c4cc5ccccc5cc4C(C)(C)c4cccc(c41)B3N(c1cccc(-c3ccccc3)c1)c1ccc(-c3ccccc3)cc1-2 ; Cc1cc2c3c(c1)N1c4cc5ccccc5cc4C(C)(C)c4cccc(c41)B3N(c1cc(-c3ccccc3)cc(-c3ccccc3)c1)c1ccccc1-2 ; Cc1cc2c3c(c1)N1c4cc5ccccc5cc4C(C)(C)c4cccc(c41)B3N(c1cccc3c1C(C)(C)c1ccccc1-3)c1cc(-c3ccccc3)ccc1-2 ; CC(C)(C)c1cc2c3c(c1)N1c4cc5ccccc5cc4C(C)(C)c4cccc(c41)B3N(c1ccc(-c3ccccc3)cc1)c1cc(-c3ccccc3)ccc1-2]

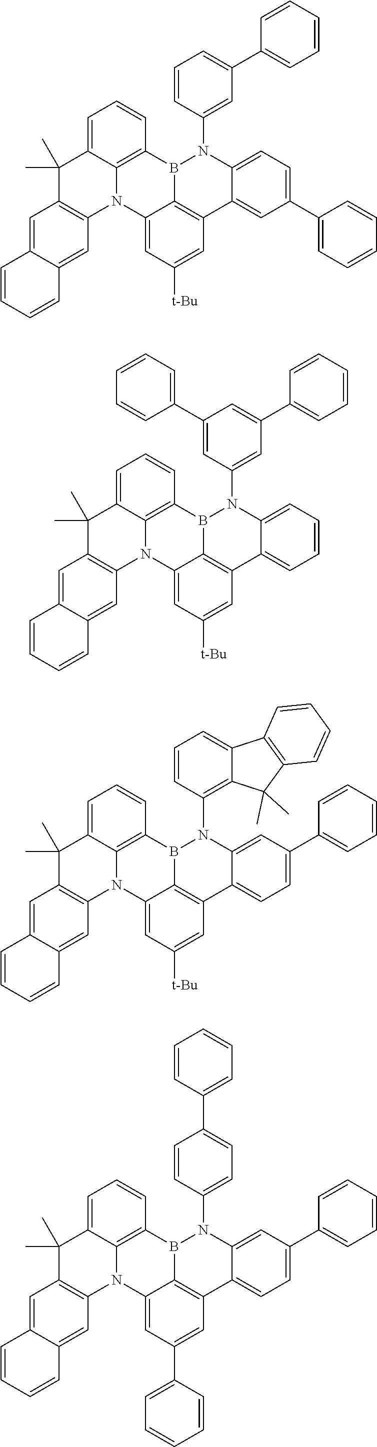 [SMILES: CC(C)(C)c1cc2c3c(c1)N1c4cc5ccccc5cc4C(C)(C)c4cccc(c41)B3N(c1cccc(-c3ccccc3)c1)c1ccc(-c3ccccc3)cc1-2 ; CC(C)(C)c1cc2c3c(c1)N1c4cc5ccccc5cc4C(C)(C)c4cccc(c41)B3N(c1cc(-c3ccccc3)cc(-c3ccccc3)c1)c1ccccc1-2 ; CC(C)(C)c1cc2c3c(c1)N1c4cc5ccccc5cc4C(C)(C)c4cccc(c41)B3N(c1cccc3c1C(C)(C)c1ccccc1-3)c1cc(-c3ccccc3)ccc1-2 ; CC1(C)c2cc3ccccc3cc2N2c3cc(-c4ccccc4)cc4c3B(c3cccc1c32)N(c1ccc(-c2ccccc2)cc1)c1cc(-c2ccccc2)ccc1-4]

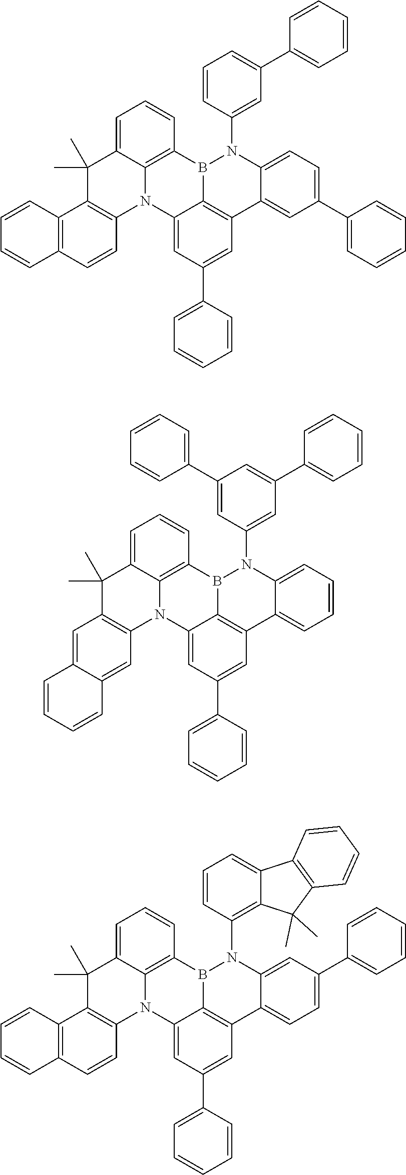 [SMILES: CC1(C)c2cccc3c2N(c2cc(-c4ccccc4)cc4c2B3N(c2cccc(-c3ccccc3)c2)c2ccc(-c3ccccc3)cc2-4)c2ccc3ccccc3c21 ; CC1(C)c2cc3ccccc3cc2N2c3cc(-c4ccccc4)cc4c3B(c3cccc1c32)N(c1cc(-c2ccccc2)cc(-c2ccccc2)c1)c1ccccc1-4 ; CC1(C)c2ccccc2-c2cccc(N3B4c5cccc6c5N(c5cc(-c7ccccc7)cc(c54)-c4ccc(-c5ccccc5)cc43)c3ccc4ccccc4c3C6(C)C)c21]

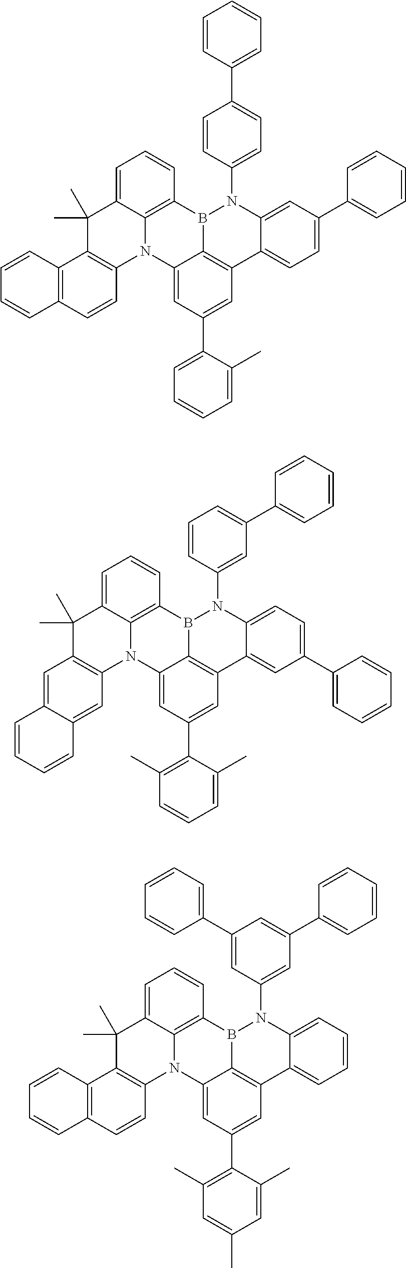 [SMILES: Cc1ccccc1-c1cc2c3c(c1)N1c4ccc5ccccc5c4C(C)(C)c4cccc(c41)B3N(c1ccc(-c3ccccc3)cc1)c1cc(-c3ccccc3)ccc1-2 ; Cc1cccc(C)c1-c1cc2c3c(c1)N1c4cc5ccccc5cc4C(C)(C)c4cccc(c41)B3N(c1cccc(-c3ccccc3)c1)c1ccc(-c3ccccc3)cc1-2 ; Cc1cc(C)c(-c2cc3c4c(c2)N2c5ccc6ccccc6c5C(C)(C)c5cccc(c52)B4N(c2cc(-c4ccccc4)cc(-c4ccccc4)c2)c2ccccc2-3)c(C)c1]

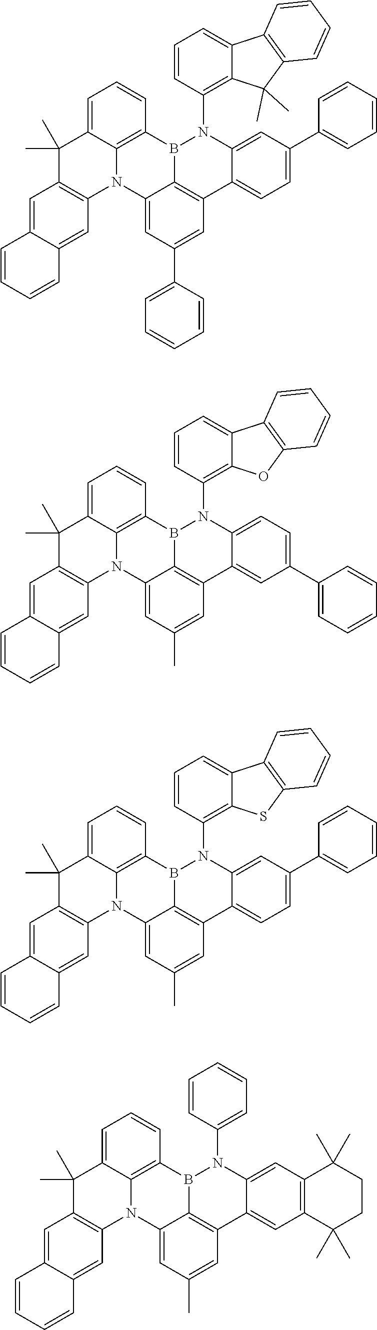 [SMILES: CC1(C)c2cc3ccccc3cc2N2c3cc(-c4ccccc4)cc4c3B(c3cccc1c32)N(c1cccc2c1C(C)(C)c1ccccc1-2)c1cc(-c2ccccc2)ccc1-4 ; Cc1cc2c3c(c1)N1c4cc5ccccc5cc4C(C)(C)c4cccc(c41)B3N(c1cccc3c1oc1ccccc13)c1ccc(-c3ccccc3)cc1-2 ; Cc1cc2c3c(c1)N1c4cc5ccccc5cc4C(C)(C)c4cccc(c41)B3N(c1cccc3c1sc1ccccc13)c1cc(-c3ccccc3)ccc1-2 ; Cc1cc2c3c(c1)N1c4cc5ccccc5cc4C(C)(C)c4cccc(c41)B3N(c1ccccc1)c1cc3c(cc1-2)C(C)(C)CCC3(C)C]

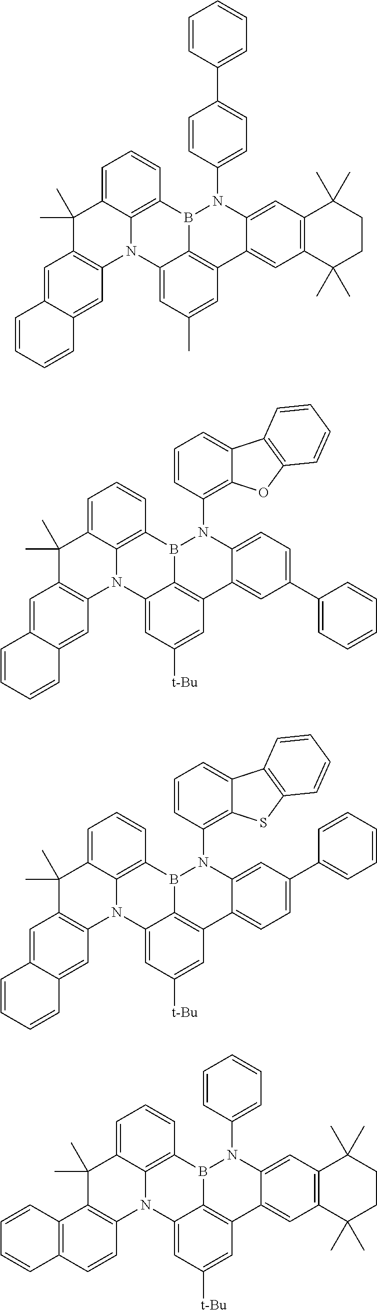 [SMILES: Cc1cc2c3c(c1)N1c4cc5ccccc5cc4C(C)(C)c4cccc(c41)B3N(c1ccc(-c3ccccc3)cc1)c1cc3c(cc1-2)C(C)(C)CCC3(C)C ; CC(C)(C)c1cc2c3c(c1)N1c4cc5ccccc5cc4C(C)(C)c4cccc(c41)B3N(c1cccc3c1oc1ccccc13)c1ccc(-c3ccccc3)cc1-2 ; CC(C)(C)c1cc2c3c(c1)N1c4cc5ccccc5cc4C(C)(C)c4cccc(c41)B3N(c1cccc3c1sc1ccccc13)c1cc(-c3ccccc3)ccc1-2 ; CC(C)(C)c1cc2c3c(c1)N1c4ccc5ccccc5c4C(C)(C)c4cccc(c41)B3N(c1ccccc1)c1cc3c(cc1-2)C(C)(C)CCC3(C)C]

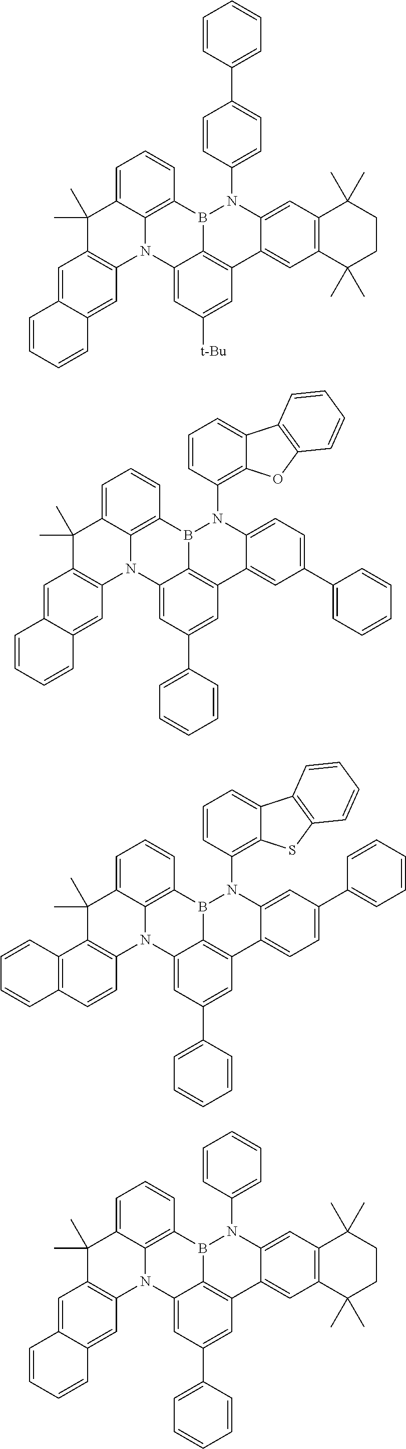

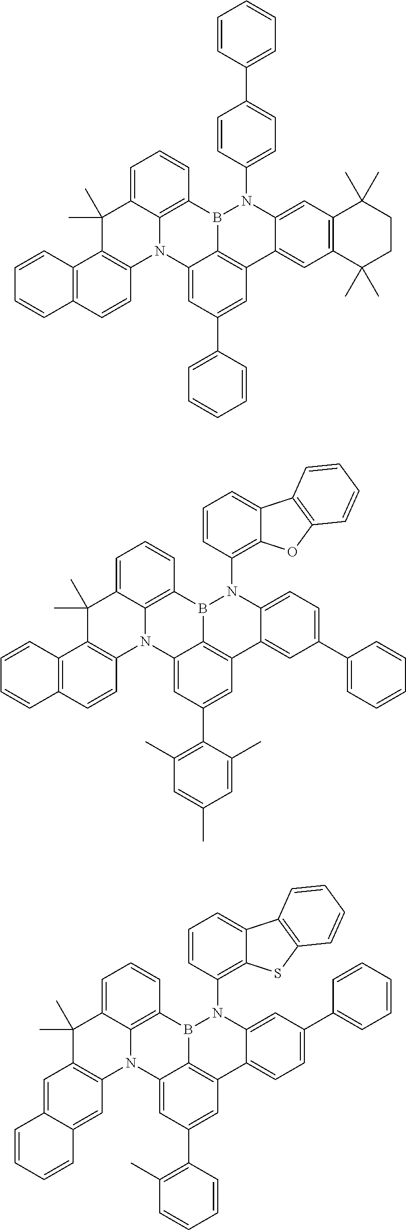 [SMILES: CC1(C)CCC(C)(C)c2cc3c(cc21)-c1cc(-c2ccccc2)cc2c1B(c1cccc4c1N2c1ccc2ccccc2c1C4(C)C)N3c1ccc(-c2ccccc2)cc1 ; Cc1cc(C)c(-c2cc3c4c(c2)N2c5ccc6ccccc6c5C(C)(C)c5cccc(c52)B4N(c2cccc4c2oc2ccccc24)c2ccc(-c4ccccc4)cc2-3)c(C)c1 ; Cc1ccccc1-c1cc2c3c(c1)N1c4cc5ccccc5cc4C(C)(C)c4cccc(c41)B3N(c1cccc3c1sc1ccccc13)c1cc(-c3ccccc3)ccc1-2]

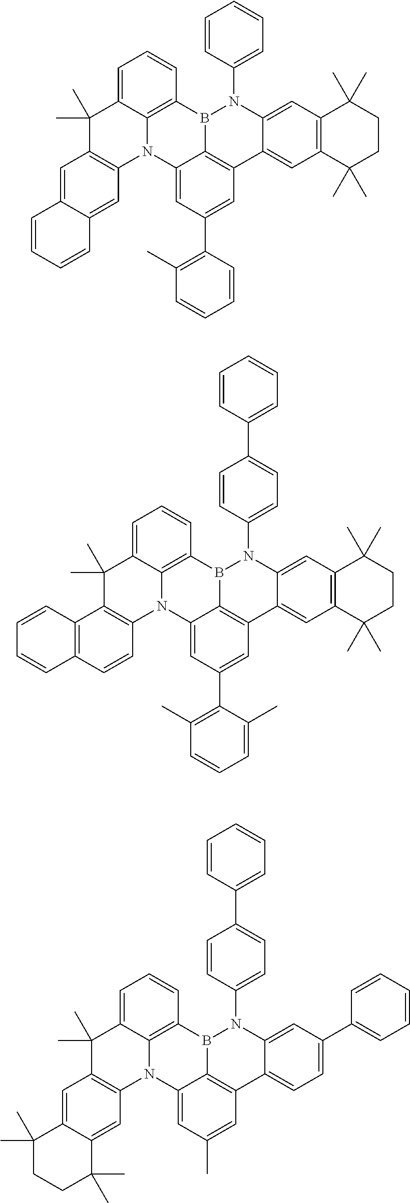 [SMILES: Cc1ccccc1-c1cc2c3c(c1)N1c4cc5ccccc5cc4C(C)(C)c4cccc(c41)B3N(c1ccccc1)c1cc3c(cc1-2)C(C)(C)CCC3(C)C ; Cc1cccc(C)c1-c1cc2c3c(c1)N1c4ccc5ccccc5c4C(C)(C)c4cccc(c41)B3N(c1ccc(-c3ccccc3)cc1)c1cc3c(cc1-2)C(C)(C)CCC3(C)C ; Cc1cc2c3c(c1)N1c4cc5c(cc4C(C)(C)c4cccc(c41)B3N(c1ccc(-c3ccccc3)cc1)c1cc(-c3ccccc3)ccc1-2)C(C)(C)CCC5(C)C]

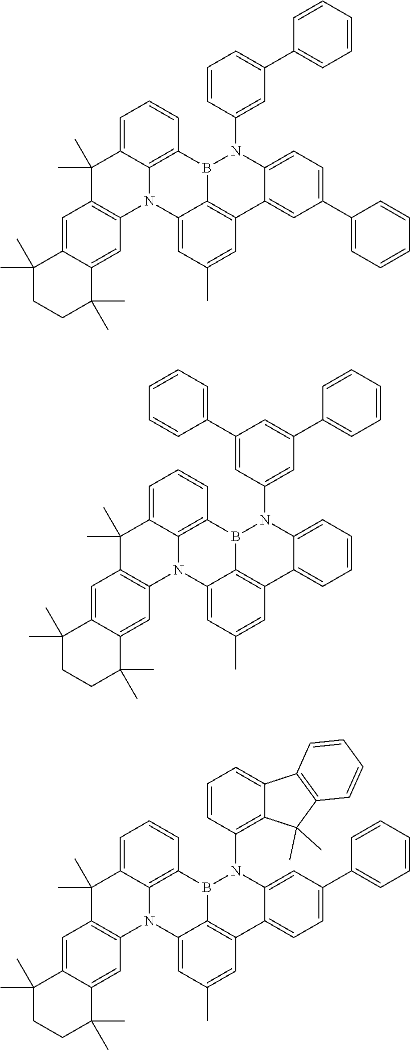 [SMILES: Cc1cc2c3c(c1)N1c4cc5c(cc4C(C)(C)c4cccc(c41)B3N(c1cccc(-c3ccccc3)c1)c1ccc(-c3ccccc3)cc1-2)C(C)(C)CCC5(C)C ; Cc1cc2c3c(c1)N1c4cc5c(cc4C(C)(C)c4cccc(c41)B3N(c1cc(-c3ccccc3)cc(-c3ccccc3)c1)c1ccccc1-2)C(C)(C)CCC5(C)C ; Cc1cc2c3c(c1)N1c4cc5c(cc4C(C)(C)c4cccc(c41)B3N(c1cccc3c1C(C)(C)c1ccccc1-3)c1cc(-c3ccccc3)ccc1-2)C(C)(C)CCC5(C)C]

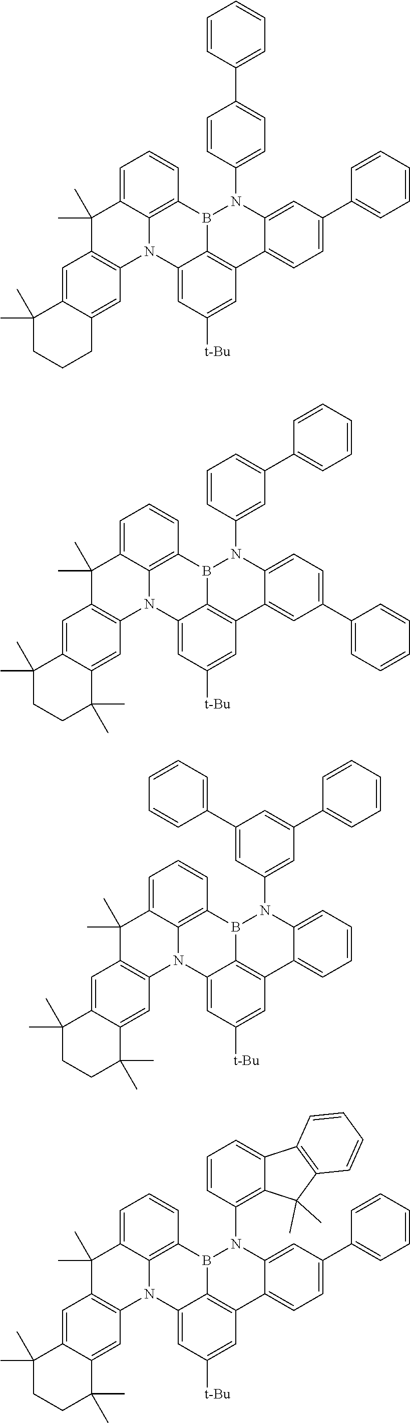 [SMILES: CC(C)(C)c1cc2c3c(c1)N1c4cc5c(cc4C(C)(C)c4cccc(c41)B3N(c1ccc(-c3ccccc3)cc1)c1cc(-c3ccccc3)ccc1-2)C(C)(C)CCC5 ; CC(C)(C)c1cc2c3c(c1)N1c4cc5c(cc4C(C)(C)c4cccc(c41)B3N(c1cccc(-c3ccccc3)c1)c1ccc(-c3ccccc3)cc1-2)C(C)(C)CCC5(C)C ; CC(C)(C)c1cc2c3c(c1)N1c4cc5c(cc4C(C)(C)c4cccc(c41)B3N(c1cc(-c3ccccc3)cc(-c3ccccc3)c1)c1ccccc1-2)C(C)(C)CCC5(C)C ; CC(C)(C)c1cc2c3c(c1)N1c4cc5c(cc4C(C)(C)c4cccc(c41)B3N(c1cccc3c1C(C)(C)c1ccccc1-3)c1cc(-c3ccccc3)ccc1-2)C(C)(C)CCC5(C)C]

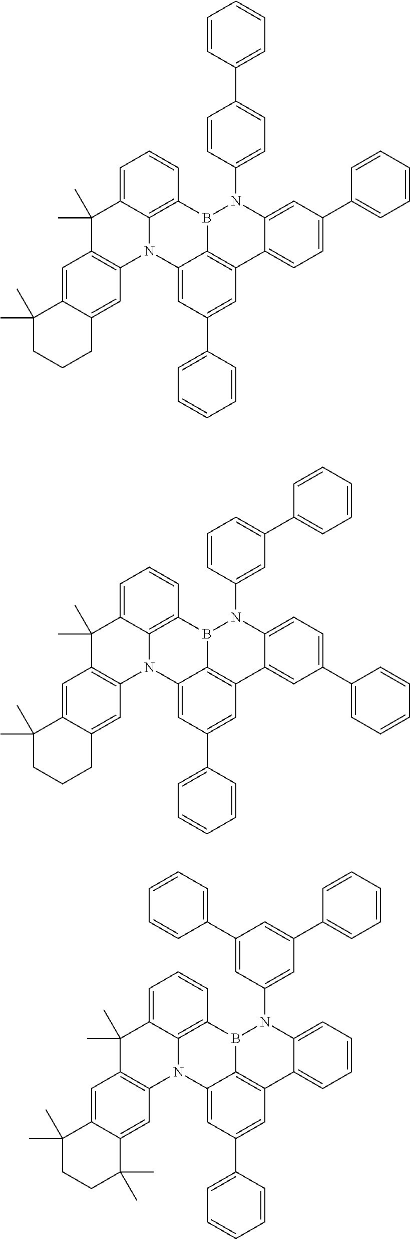 [SMILES: CC1(C)CCCc2cc3c(cc21)C(C)(C)c1cccc2c1N3c1cc(-c3ccccc3)cc3c1B2N(c1ccc(-c2ccccc2)cc1)c1cc(-c2ccccc2)ccc1-3 ; CC1(C)CCCc2cc3c(cc21)C(C)(C)c1cccc2c1N3c1cc(-c3ccccc3)cc3c1B2N(c1cccc(-c2ccccc2)c1)c1ccc(-c2ccccc2)cc1-3 ; CC1(C)CCC(C)(C)c2cc3c(cc21)N1c2cc(-c4ccccc4)cc4c2B(c2cccc(c21)C3(C)C)N(c1cc(-c2ccccc2)cc(-c2ccccc2)c1)c1ccccc1-4]

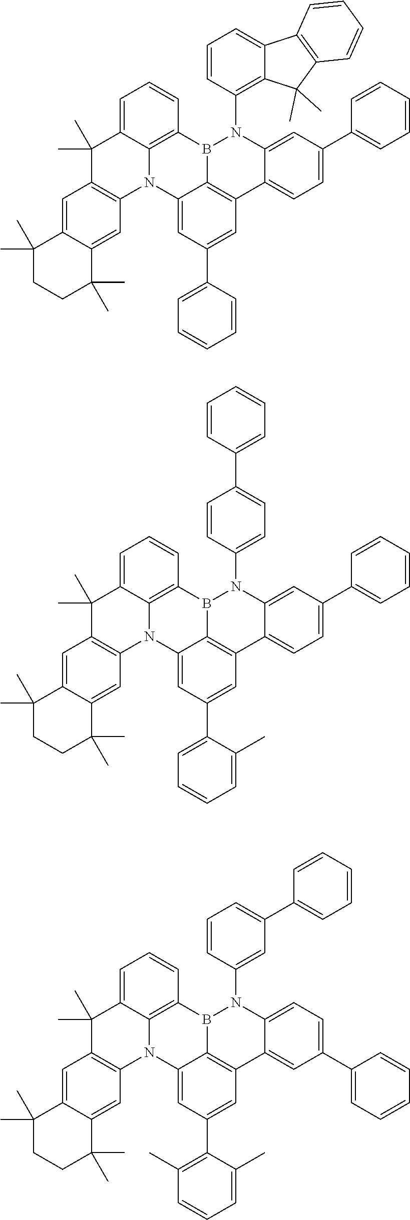 [SMILES: CC1(C)CCC(C)(C)c2cc3c(cc21)N1c2cc(-c4ccccc4)cc4c2B(c2cccc(c21)C3(C)C)N(c1cccc2c1C(C)(C)c1ccccc1-2)c1cc(-c2ccccc2)ccc1-4 ; Cc1ccccc1-c1cc2c3c(c1)N1c4cc5c(cc4C(C)(C)c4cccc(c41)B3N(c1ccc(-c3ccccc3)cc1)c1cc(-c3ccccc3)ccc1-2)C(C)(C)CCC5(C)C ; Cc1cccc(C)c1-c1cc2c3c(c1)N1c4cc5c(cc4C(C)(C)c4cccc(c41)B3N(c1cccc(-c3ccccc3)c1)c1ccc(-c3ccccc3)cc1-2)C(C)(C)CCC5(C)C]

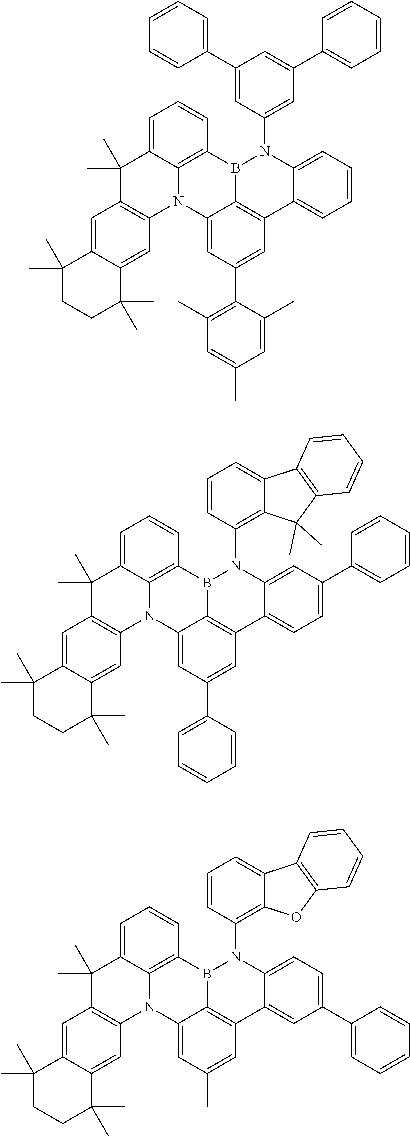 [SMILES: Cc1cc(C)c(-c2cc3c4c(c2)N2c5cc6c(cc5C(C)(C)c5cccc(c52)B4N(c2cc(-c4ccccc4)cc(-c4ccccc4)c2)c2ccccc2-3)C(C)(C)CCC6(C)C)c(C)c1 ; CC1(C)CCC(C)(C)c2cc3c(cc21)N1c2cc(-c4ccccc4)cc4c2B(c2cccc(c21)C3(C)C)N(c1cccc2c1C(C)(C)c1ccccc1-2)c1cc(-c2ccccc2)ccc1-4 ; Cc1cc2c3c(c1)N1c4cc5c(cc4C(C)(C)c4cccc(c41)B3N(c1cccc3c1oc1ccccc13)c1ccc(-c3ccccc3)cc1-2)C(C)(C)CCC5(C)C]

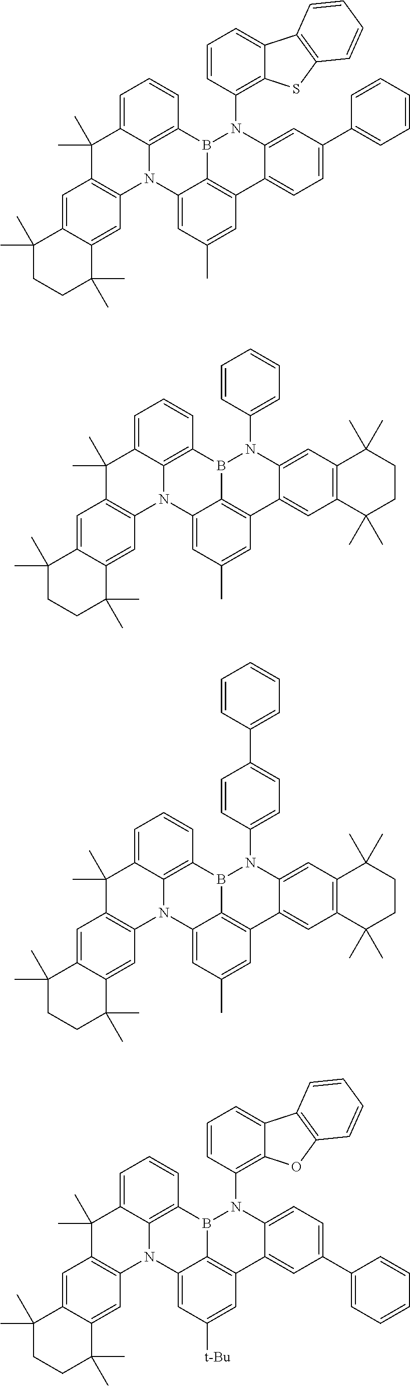 [SMILES: Cc1cc2c3c(c1)N1c4cc5c(cc4C(C)(C)c4cccc(c41)B3N(c1cccc3c1sc1ccccc13)c1cc(-c3ccccc3)ccc1-2)C(C)(C)CCC5(C)C ; Cc1cc2c3c(c1)N1c4cc5c(cc4C(C)(C)c4cccc(c41)B3N(c1ccccc1)c1cc3c(cc1-2)C(C)(C)CCC3(C)C)C(C)(C)CCC5(C)C ; Cc1cc2c3c(c1)N1c4cc5c(cc4C(C)(C)c4cccc(c41)B3N(c1ccc(-c3ccccc3)cc1)c1cc3c(cc1-2)C(C)(C)CCC3(C)C)C(C)(C)CCC5(C)C ; CC(C)(C)c1cc2c3c(c1)N1c4cc5c(cc4C(C)(C)c4cccc(c41)B3N(c1cccc3c1oc1ccccc13)c1ccc(-c3ccccc3)cc1-2)C(C)(C)CCC5(C)C]

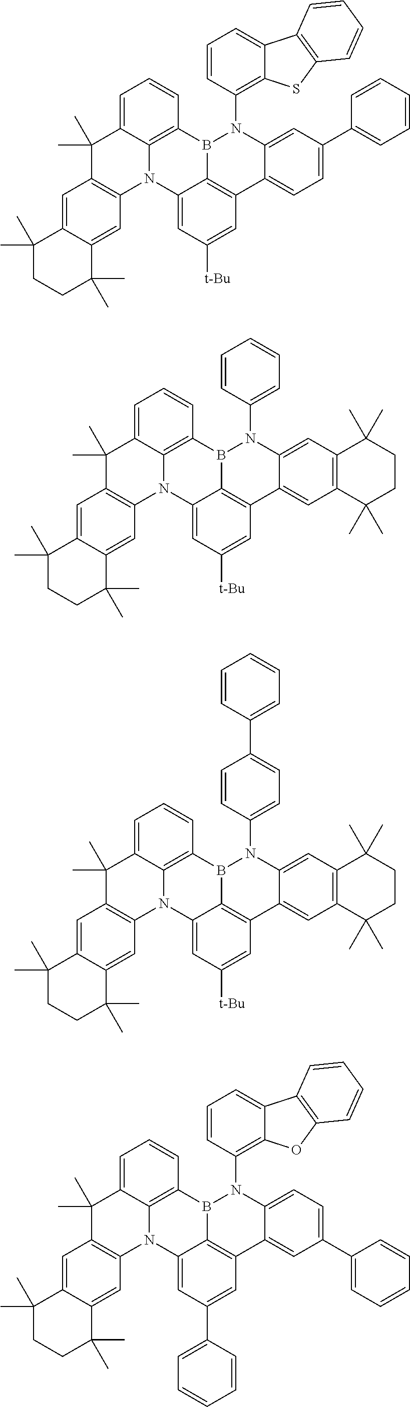 [SMILES: CC(C)(C)c1cc2c3c(c1)N1c4cc5c(cc4C(C)(C)c4cccc(c41)B3N(c1cccc3c1sc1ccccc13)c1cc(-c3ccccc3)ccc1-2)C(C)(C)CCC5(C)C ; CC(C)(C)c1cc2c3c(c1)N1c4cc5c(cc4C(C)(C)c4cccc(c41)B3N(c1ccccc1)c1cc3c(cc1-2)C(C)(C)CCC3(C)C)C(C)(C)CCC5(C)C ; CC(C)(C)c1cc2c3c(c1)N1c4cc5c(cc4C(C)(C)c4cccc(c41)B3N(c1ccc(-c3ccccc3)cc1)c1cc3c(cc1-2)C(C)(C)CCC3(C)C)C(C)(C)CCC5(C)C ; CC1(C)CCC(C)(C)c2cc3c(cc21)N1c2cc(-c4ccccc4)cc4c2B(c2cccc(c21)C3(C)C)N(c1cccc2c1oc1ccccc12)c1ccc(-c2ccccc2)cc1-4]

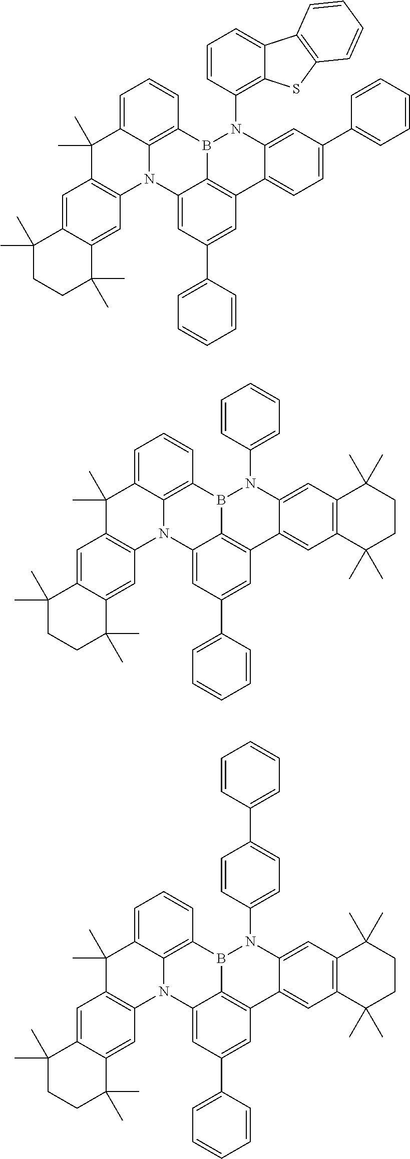 [SMILES: CC1(C)CCC(C)(C)c2cc3c(cc21)N1c2cc(-c4ccccc4)cc4c2B(c2cccc(c21)C3(C)C)N(c1cccc2c1sc1ccccc12)c1cc(-c2ccccc2)ccc1-4 ; CC1(C)CCC(C)(C)c2cc3c(cc21)-c1cc(-c2ccccc2)cc2c1B(c1cccc4c1N2c1cc2c(cc1C4(C)C)C(C)(C)CCC2(C)C)N3c1ccccc1 ; CC1(C)CCC(C)(C)c2cc3c(cc21)-c1cc(-c2ccccc2)cc2c1B(c1cccc4c1N2c1cc2c(cc1C4(C)C)C(C)(C)CCC2(C)C)N3c1ccc(-c2ccccc2)cc1]

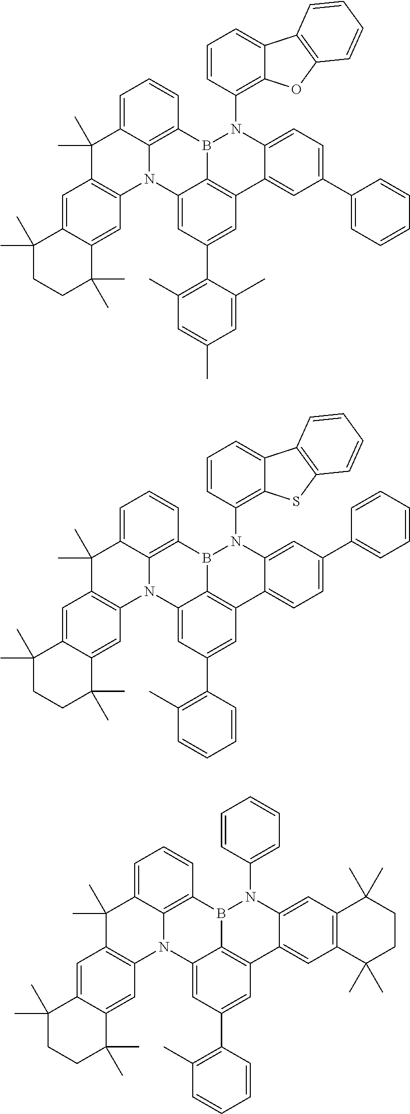 [SMILES: Cc1cc(C)c(-c2cc3c4c(c2)N2c5cc6c(cc5C(C)(C)c5cccc(c52)B4N(c2cccc4c2oc2ccccc24)c2ccc(-c4ccccc4)cc2-3)C(C)(C)CCC6(C)C)c(C)c1 ; Cc1ccccc1-c1cc2c3c(c1)N1c4cc5c(cc4C(C)(C)c4cccc(c41)B3N(c1cccc3c1sc1ccccc13)c1cc(-c3ccccc3)ccc1-2)C(C)(C)CCC5(C)C ; Cc1ccccc1-c1cc2c3c(c1)N1c4cc5c(cc4C(C)(C)c4cccc(c41)B3N(c1ccccc1)c1cc3c(cc1-2)C(C)(C)CCC3(C)C)C(C)(C)CCC5(C)C]

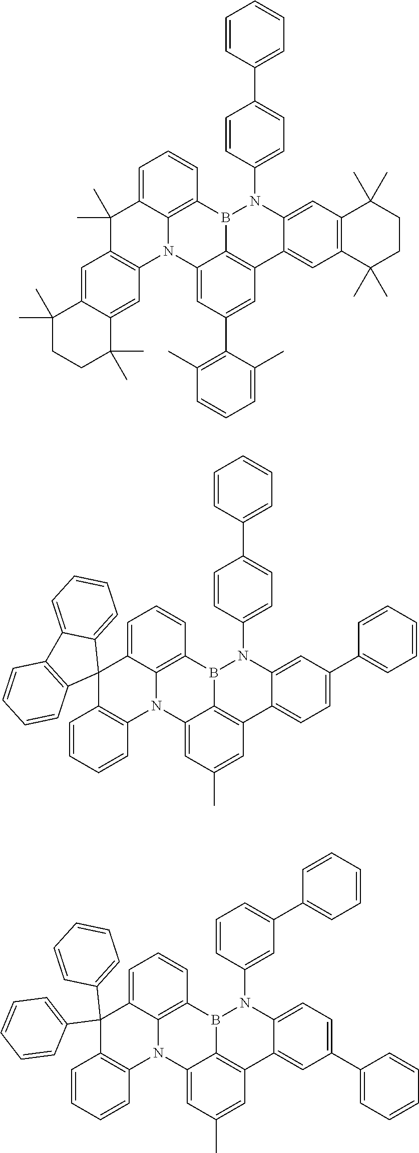

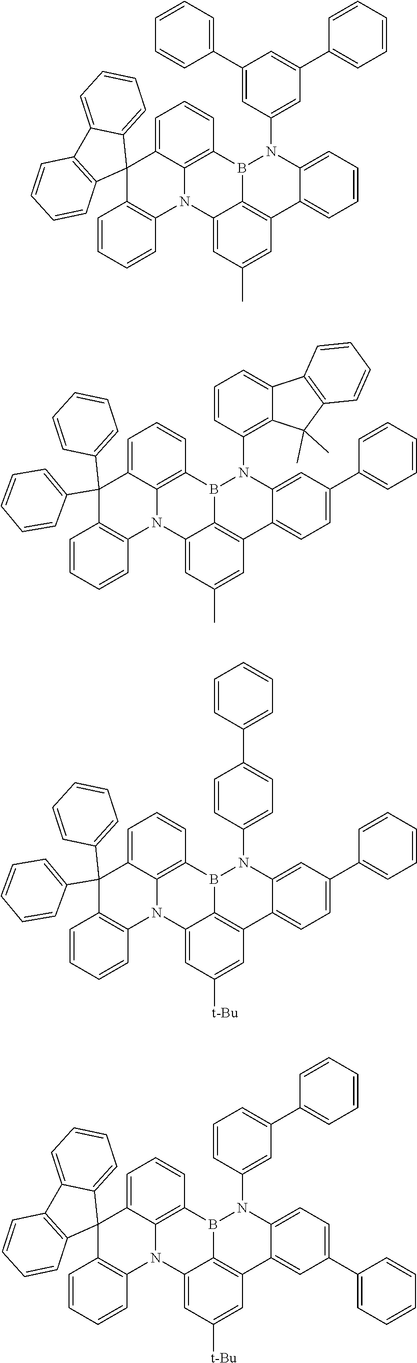

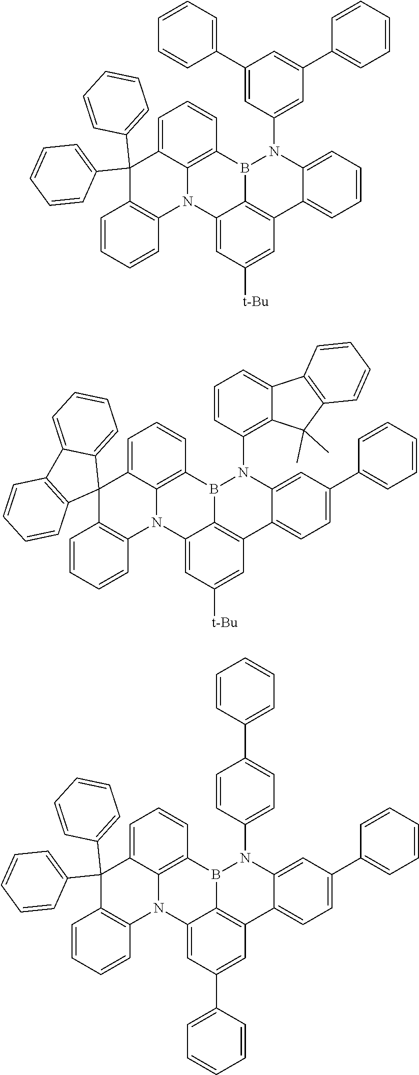 [SMILES: CC(C)(C)c1cc2c3c(c1)N1c4ccccc4C(c4ccccc4)(c4ccccc4)c4cccc(c41)B3N(c1cc(-c3ccccc3)cc(-c3ccccc3)c1)c1ccccc1-2 ; CC(C)(C)c1cc2c3c(c1)N1c4ccccc4C4(c5ccccc5-c5ccccc54)c4cccc(c41)B3N(c1cccc3c1C(C)(C)c1ccccc1-3)c1cc(-c3ccccc3)ccc1-2 ; c1ccc(-c2ccc(N3B4c5cccc6c5N(c5ccccc5C6(c5ccccc5)c5ccccc5)c5cc(-c6ccccc6)cc(c54)-c4ccc(-c5ccccc5)cc43)cc2)cc1]

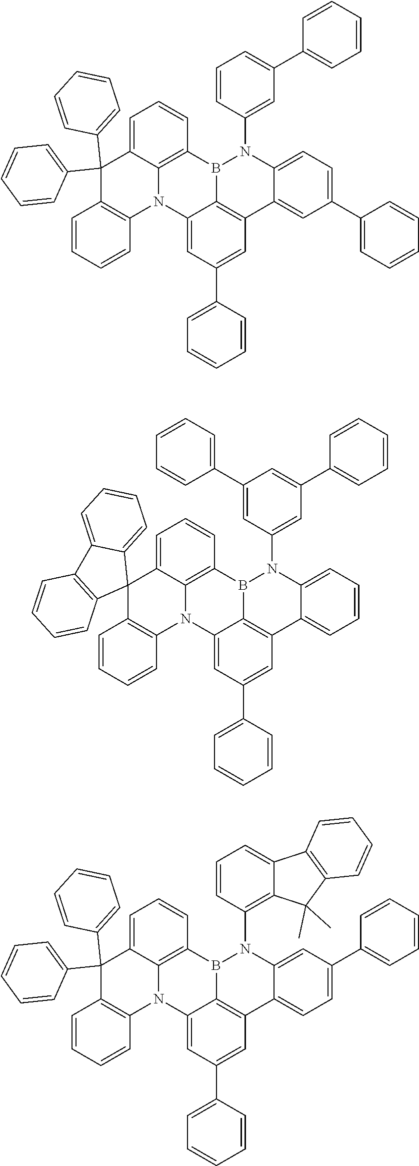 [SMILES: c1ccc(-c2cccc(N3B4c5cccc6c5N(c5ccccc5C6(c5ccccc5)c5ccccc5)c5cc(-c6ccccc6)cc(c54)-c4cc(-c5ccccc5)ccc43)c2)cc1 ; c1ccc(-c2cc(-c3ccccc3)cc(N3B4c5cccc6c5N(c5ccccc5C65c6ccccc6-c6ccccc65)c5cc(-c6ccccc6)cc(c54)-c4ccccc43)c2)cc1 ; CC1(C)c2ccccc2-c2cccc(N3B4c5cccc6c5N(c5ccccc5C6(c5ccccc5)c5ccccc5)c5cc(-c6ccccc6)cc(c54)-c4ccc(-c5ccccc5)cc43)c21]

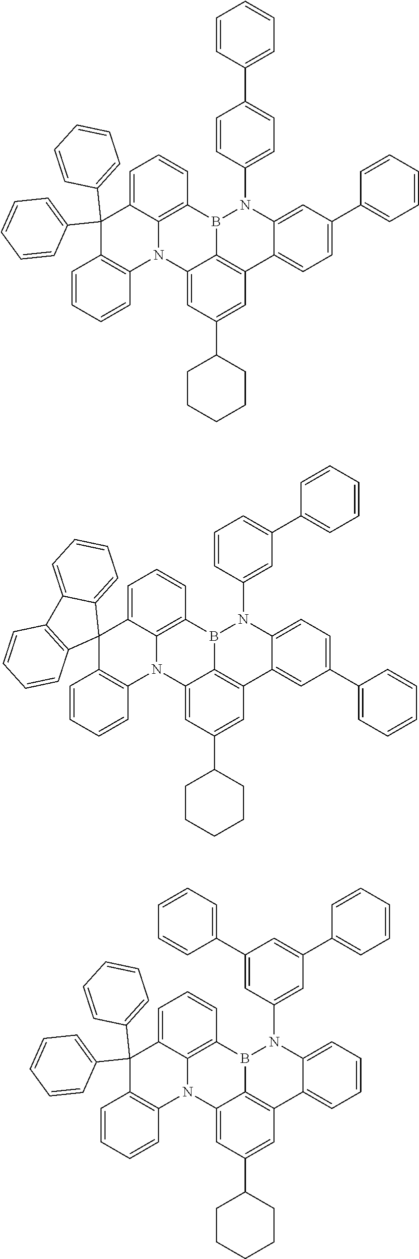 [SMILES: c1ccc(-c2ccc(N3B4c5cccc6c5N(c5ccccc5C6(c5ccccc5)c5ccccc5)c5cc(C6CCCCC6)cc(c54)-c4ccc(-c5ccccc5)cc43)cc2)cc1 ; c1ccc(-c2cccc(N3B4c5cccc6c5N(c5ccccc5C65c6ccccc6-c6ccccc65)c5cc(C6CCCCC6)cc(c54)-c4cc(-c5ccccc5)ccc43)c2)cc1 ; c1ccc(-c2cc(-c3ccccc3)cc(N3B4c5cccc6c5N(c5ccccc5C6(c5ccccc5)c5ccccc5)c5cc(C6CCCCC6)cc(c54)-c4ccccc43)c2)cc1]

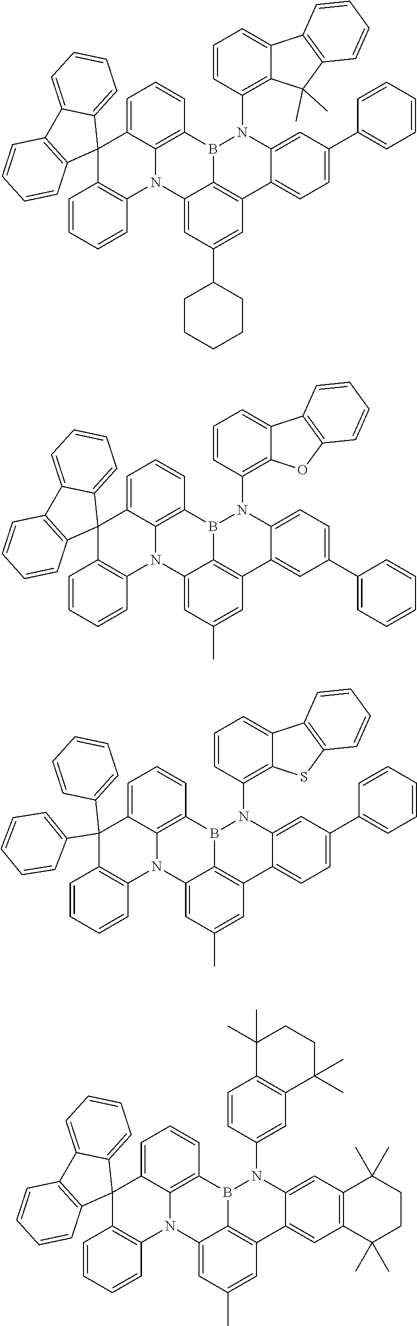 [SMILES: CC1(C)c2ccccc2-c2cccc(N3B4c5cccc6c5N(c5ccccc5C65c6ccccc6-c6ccccc65)c5cc(C6CCCCC6)cc(c54)-c4ccc(-c5ccccc5)cc43)c21 ; Cc1cc2c3c(c1)N1c4ccccc4C4(c5ccccc5-c5ccccc54)c4cccc(c41)B3N(c1cccc3c1oc1ccccc13)c1ccc(-c3ccccc3)cc1-2 ; Cc1cc2c3c(c1)N1c4ccccc4C(c4ccccc4)(c4ccccc4)c4cccc(c41)B3N(c1cccc3c1sc1ccccc13)c1cc(-c3ccccc3)ccc1-2 ; Cc1cc2c3c(c1)N1c4ccccc4C4(c5ccccc5-c5ccccc54)c4cccc(c41)B3N(c1ccc3c(c1)C(C)(C)CCC3(C)C)c1cc3c(cc1-2)C(C)(C)CCC3(C)C]

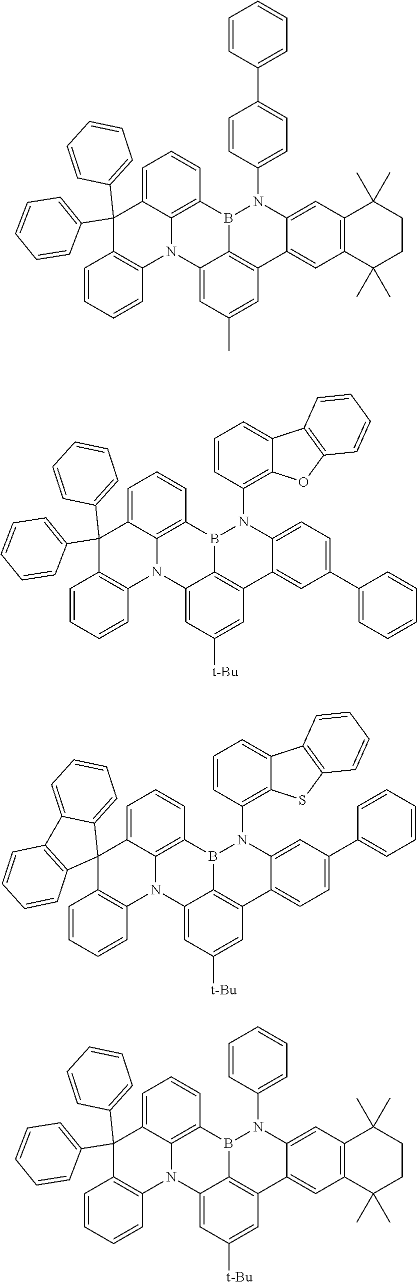 [SMILES: Cc1cc2c3c(c1)N1c4ccccc4C(c4ccccc4)(c4ccccc4)c4cccc(c41)B3N(c1ccc(-c3ccccc3)cc1)c1cc3c(cc1-2)C(C)(C)CCC3(C)C ; CC(C)(C)c1cc2c3c(c1)N1c4ccccc4C(c4ccccc4)(c4ccccc4)c4cccc(c41)B3N(c1cccc3c1oc1ccccc13)c1ccc(-c3ccccc3)cc1-2 ; CC(C)(C)c1cc2c3c(c1)N1c4ccccc4C4(c5ccccc5-c5ccccc54)c4cccc(c41)B3N(c1cccc3c1sc1ccccc13)c1cc(-c3ccccc3)ccc1-2 ; CC(C)(C)c1cc2c3c(c1)N1c4ccccc4C(c4ccccc4)(c4ccccc4)c4cccc(c41)B3N(c1ccccc1)c1cc3c(cc1-2)C(C)(C)CCC3(C)C]

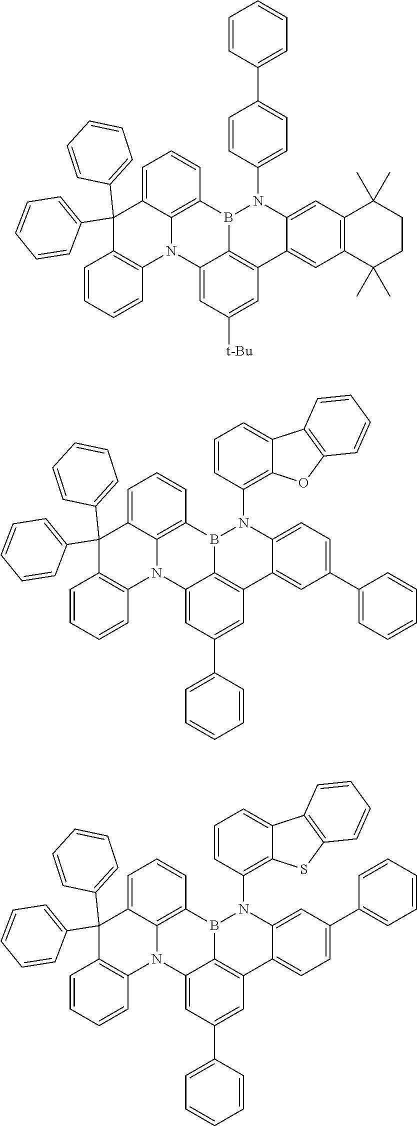 [SMILES: CC(C)(C)c1cc2c3c(c1)N1c4ccccc4C(c4ccccc4)(c4ccccc4)c4cccc(c41)B3N(c1ccc(-c3ccccc3)cc1)c1cc3c(cc1-2)C(C)(C)CCC3(C)C ; c1ccc(-c2ccc3c(c2)-c2cc(-c4ccccc4)cc4c2B(c2cccc5c2N4c2ccccc2C5(c2ccccc2)c2ccccc2)N3c2cccc3c2oc2ccccc23)cc1 ; c1ccc(-c2ccc3c(c2)N(c2cccc4c2sc2ccccc24)B2c4cccc5c4N(c4ccccc4C5(c4ccccc4)c4ccccc4)c4cc(-c5ccccc5)cc-3c42)cc1]

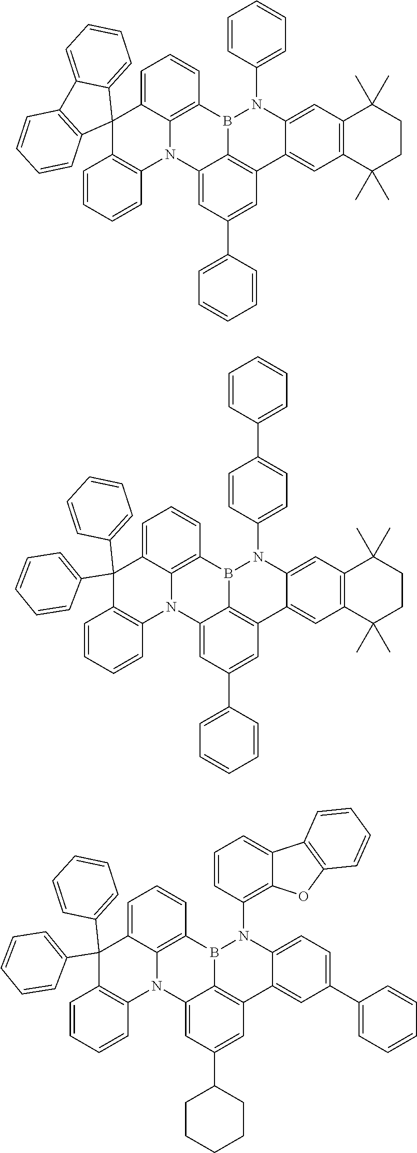

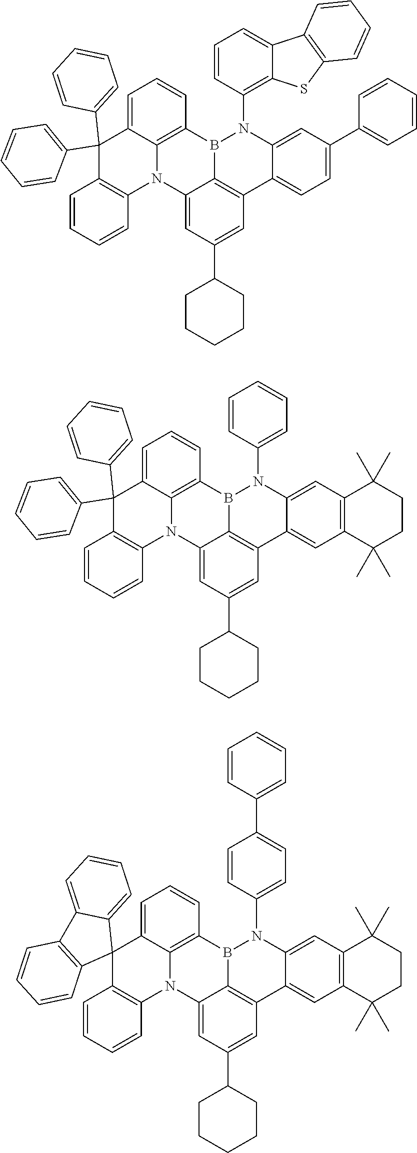

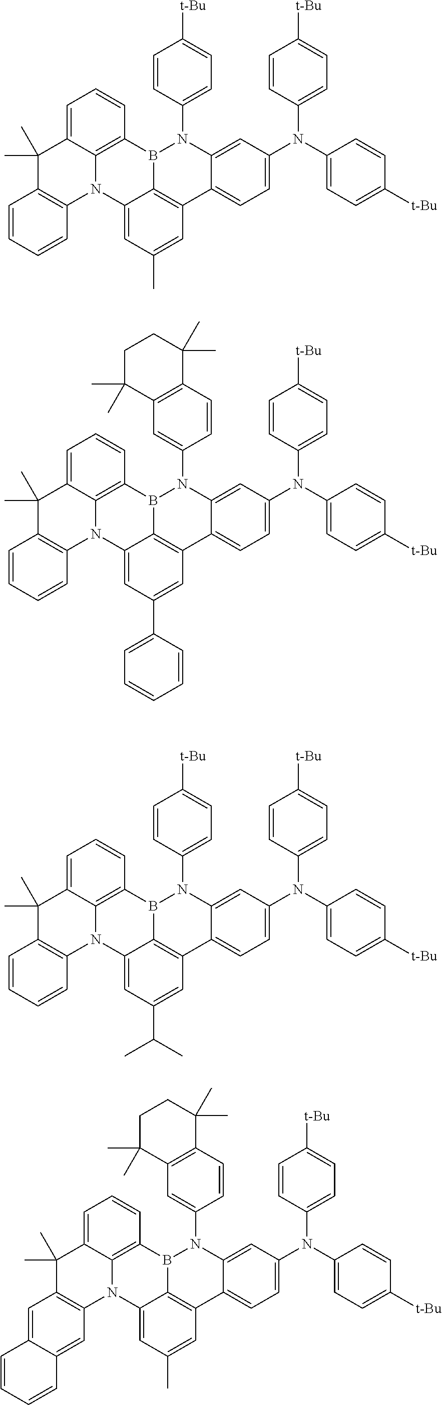

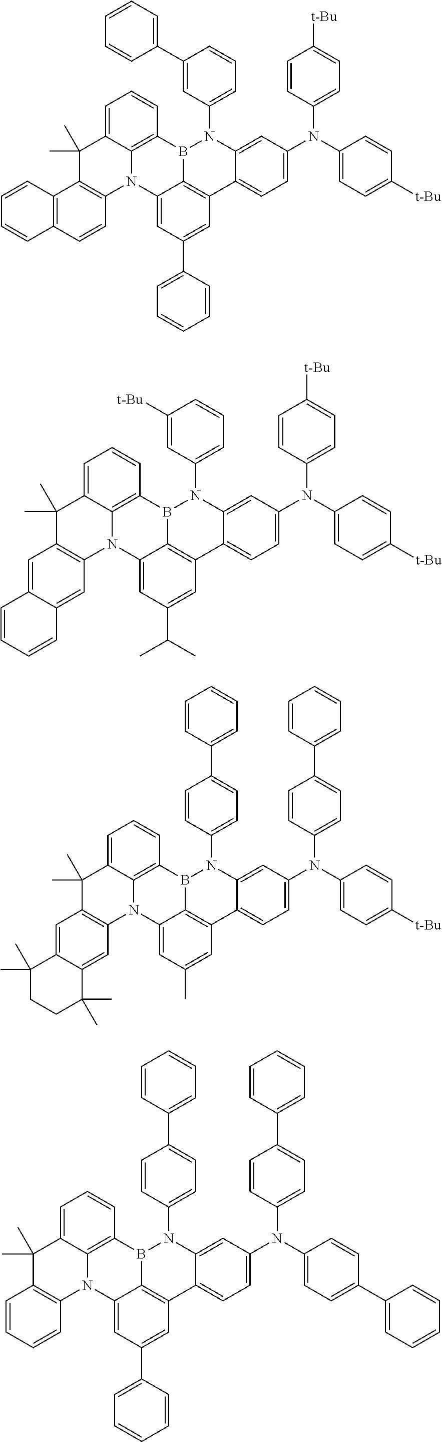

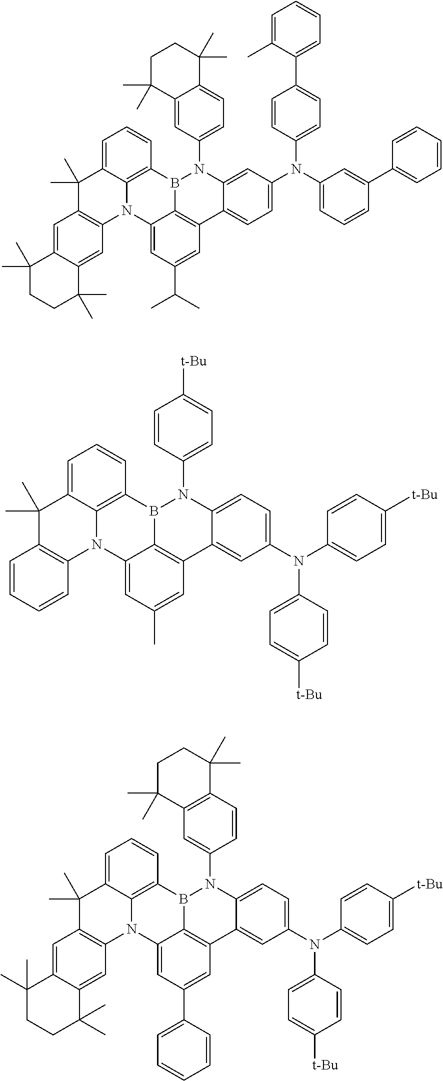 [SMILES: Cc1ccccc1-c1ccc(N(c2cccc(-c3ccccc3)c2)c2ccc3c(c2)N(c2ccc4c(c2)C(C)(C)CCC4(C)C)B2c4cccc5c4N(c4cc6c(cc4C5(C)C)C(C)(C)CCC6(C)C)c4cc(C(C)C)cc-3c42)cc1 ; Cc1cc2c3c(c1)N1c4ccccc4C(C)(C)c4cccc(c41)B3N(c1ccc(C(C)(C)C)cc1)c1ccc(N(c3ccc(C(C)(C)C)cc3)c3ccc(C(C)(C)C)cc3)cc1-2 ; CC(C)(C)c1ccc(N(c2ccc(C(C)(C)C)cc2)c2ccc3c(c2)-c2cc(-c4ccccc4)cc4c2B(c2cccc5c2N4c2cc4c(cc2C5(C)C)C(C)(C)CCC4(C)C)N3c2ccc3c(c2)C(C)(C)CCC3(C)C)cc1]

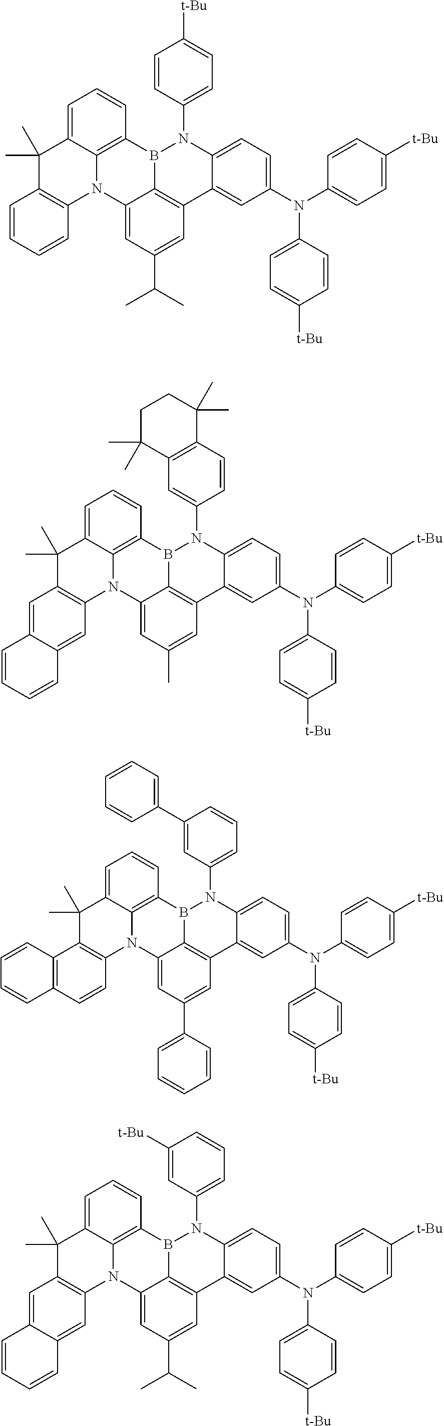

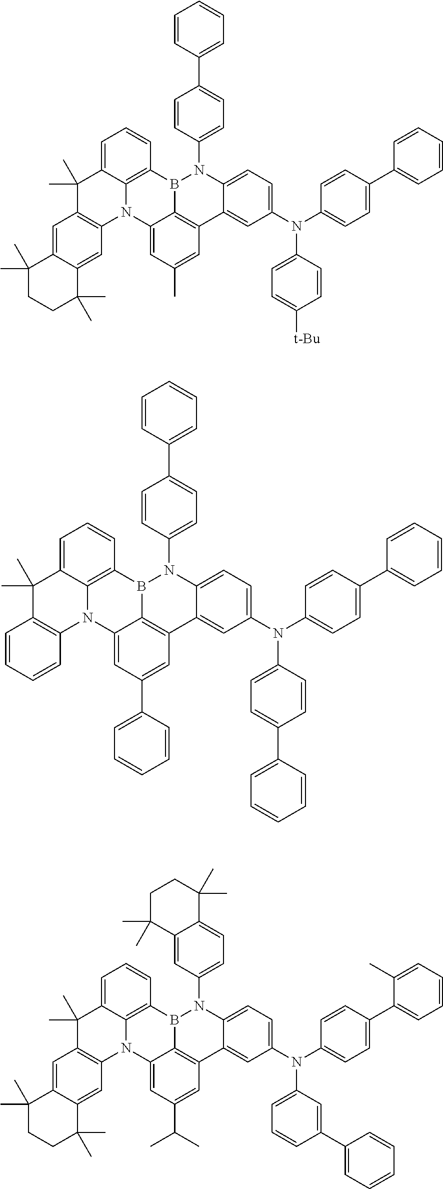 [SMILES: Cc1cc2c3c(c1)N1c4cc5c(cc4C(C)(C)c4cccc(c41)B3N(c1ccc(-c3ccccc3)cc1)c1ccc(N(c3ccc(-c4ccccc4)cc3)c3ccc(C(C)(C)C)cc3)cc1-2)C(C)(C)CCC5(C)C ; CC1(C)c2ccccc2N2c3cc(-c4ccccc4)cc4c3B(c3cccc1c32)N(c1ccc(-c2ccccc2)cc1)c1ccc(N(c2ccc(-c3ccccc3)cc2)c2ccc(-c3ccccc3)cc2)cc1-4 ; Cc1ccccc1-c1ccc(N(c2cccc(-c3ccccc3)c2)c2ccc3c(c2)-c2cc(C(C)C)cc4c2B(c2cccc5c2N4c2cc4c(cc2C5(C)C)C(C)(C)CCC4(C)C)N3c2ccc3c(c2)C(C)(C)CCC3(C)C)cc1]

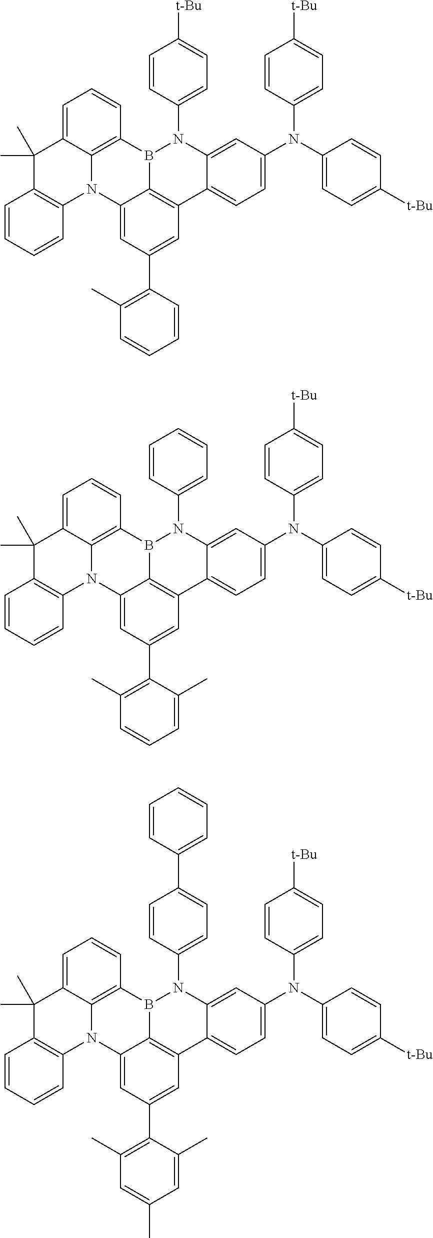 [SMILES: Cc1ccccc1-c1cc2c3c(c1)N1c4ccccc4C(C)(C)c4cccc(c41)B3N(c1ccc(C(C)(C)C)cc1)c1cc(N(c3ccc(C(C)(C)C)cc3)c3ccc(C(C)(C)C)cc3)ccc1-2 ; Cc1cccc(C)c1-c1cc2c3c(c1)N1c4ccccc4C(C)(C)c4cccc(c41)B3N(c1ccccc1)c1cc(N(c3ccc(C(C)(C)C)cc3)c3ccc(C(C)(C)C)cc3)ccc1-2 ; Cc1cc(C)c(-c2cc3c4c(c2)N2c5ccccc5C(C)(C)c5cccc(c52)B4N(c2ccc(-c4ccccc4)cc2)c2cc(N(c4ccc(C(C)(C)C)cc4)c4ccc(C(C)(C)C)cc4)ccc2-3)c(C)c1]

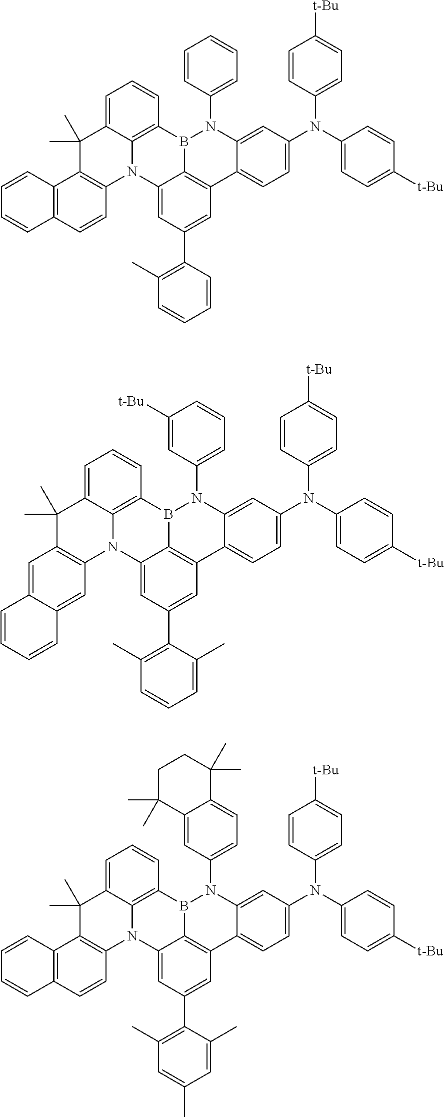 [SMILES: Cc1ccccc1-c1cc2c3c(c1)N1c4ccc5ccccc5c4C(C)(C)c4cccc(c41)B3N(c1ccccc1)c1cc(N(c3ccc(C(C)(C)C)cc3)c3ccc(C(C)(C)C)cc3)ccc1-2 ; Cc1cccc(C)c1-c1cc2c3c(c1)N1c4cc5ccccc5cc4C(C)(C)c4cccc(c41)B3N(c1cccc(C(C)(C)C)c1)c1cc(N(c3ccc(C(C)(C)C)cc3)c3ccc(C(C)(C)C)cc3)ccc1-2 ; Cc1cc(C)c(-c2cc3c4c(c2)N2c5ccc6ccccc6c5C(C)(C)c5cccc(c52)B4N(c2ccc4c(c2)C(C)(C)CCC4(C)C)c2cc(N(c4ccc(C(C)(C)C)cc4)c4ccc(C(C)(C)C)cc4)ccc2-3)c(C)c1]

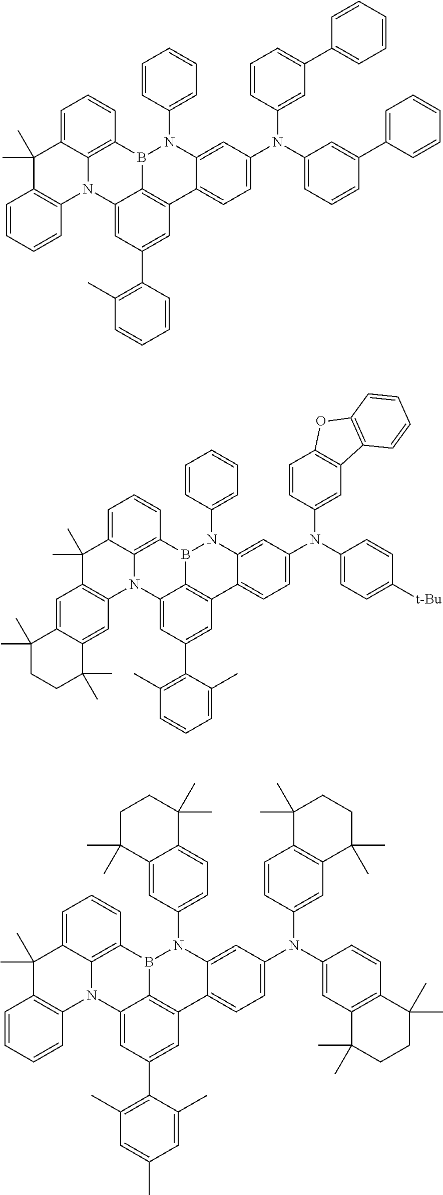

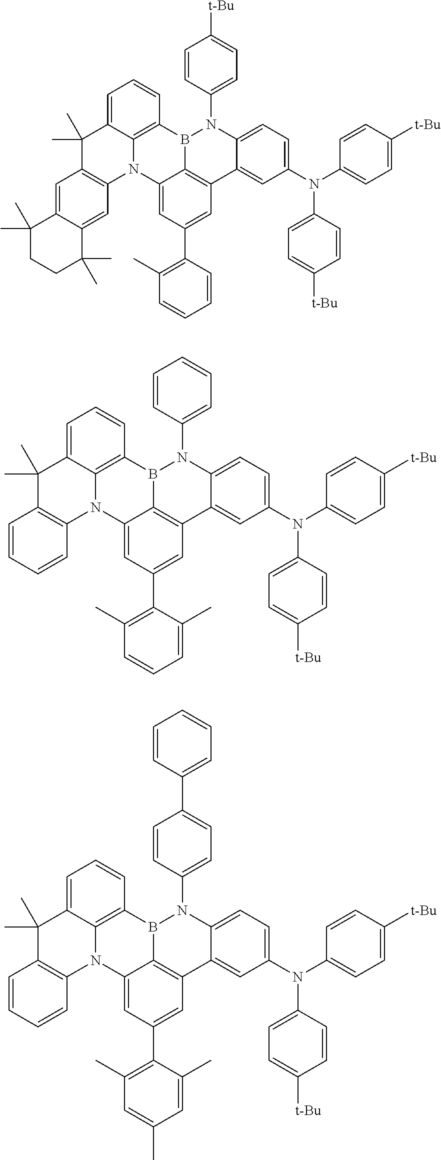

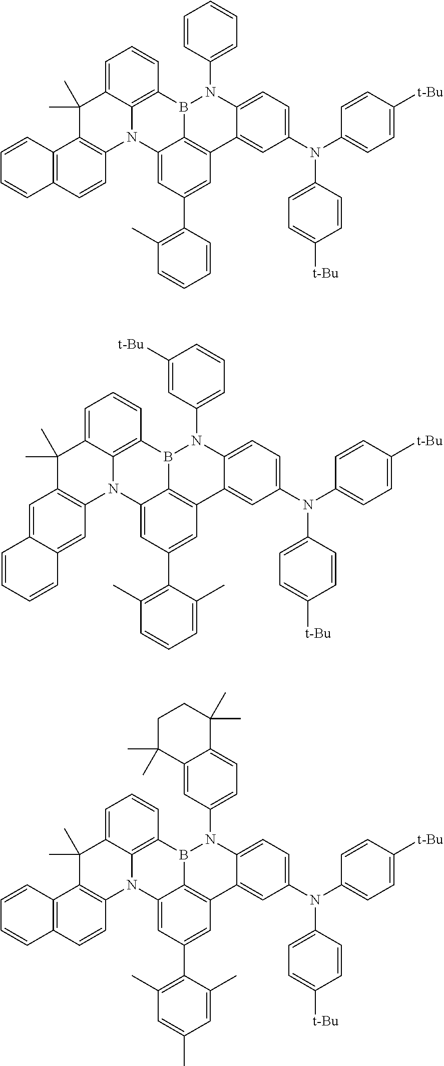 [SMILES: Cc1ccccc1-c1cc2c3c(c1)N1c4ccc5ccccc5c4C(C)(C)c4cccc(c41)B3N(c1ccccc1)c1ccc(N(c3ccc(C(C)(C)C)cc3)c3ccc(C(C)(C)C)cc3)cc1-2 ; Cc1cccc(C)c1-c1cc2c3c(c1)N1c4cc5ccccc5cc4C(C)(C)c4cccc(c41)B3N(c1cccc(C(C)(C)C)c1)c1ccc(N(c3ccc(C(C)(C)C)cc3)c3ccc(C(C)(C)C)cc3)cc1-2 ; Cc1cc(C)c(-c2cc3c4c(c2)N2c5ccc6ccccc6c5C(C)(C)c5cccc(c52)B4N(c2ccc4c(c2)C(C)(C)CCC4(C)C)c2ccc(N(c4ccc(C(C)(C)C)cc4)c4ccc(C(C)(C)C)cc4)cc2-3)c(C)c1]

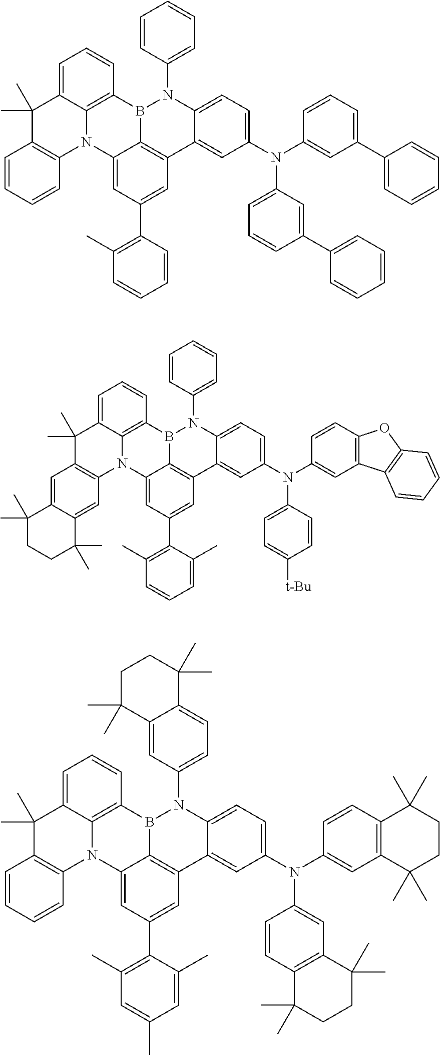 [SMILES: Cc1ccccc1-c1cc2c3c(c1)N1c4ccccc4C(C)(C)c4cccc(c41)B3N(c1ccccc1)c1ccc(N(c3cccc(-c4ccccc4)c3)c3cccc(-c4ccccc4)c3)cc1-2 ; Cc1cccc(C)c1-c1cc2c3c(c1)N1c4cc5c(cc4C(C)(C)c4cccc(c41)B3N(c1ccccc1)c1ccc(N(c3ccc(C(C)(C)C)cc3)c3ccc4oc6ccccc6c4c3)cc1-2)C(C)(C)CCC5(C)C ; Cc1cc(C)c(-c2cc3c4c(c2)N2c5ccccc5C(C)(C)c5cccc(c52)B4N(c2ccc4c(c2)C(C)(C)CCC4(C)C)c2ccc(N(c4ccc5c(c4)C(C)(C)CCC5(C)C)c4ccc5c(c4)C(C)(C)CCC5(C)C)cc2-3)c(C)c1]

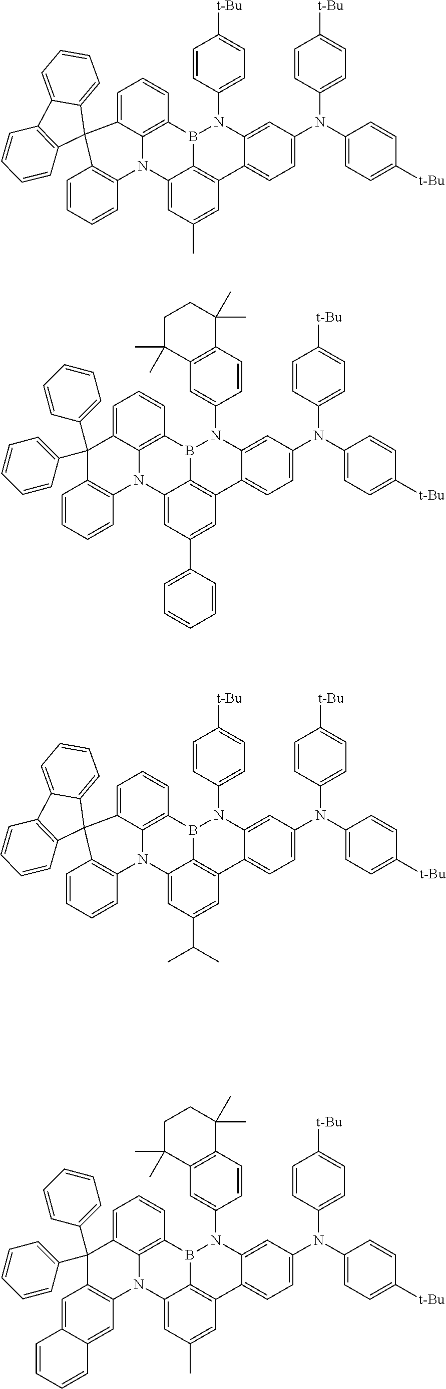

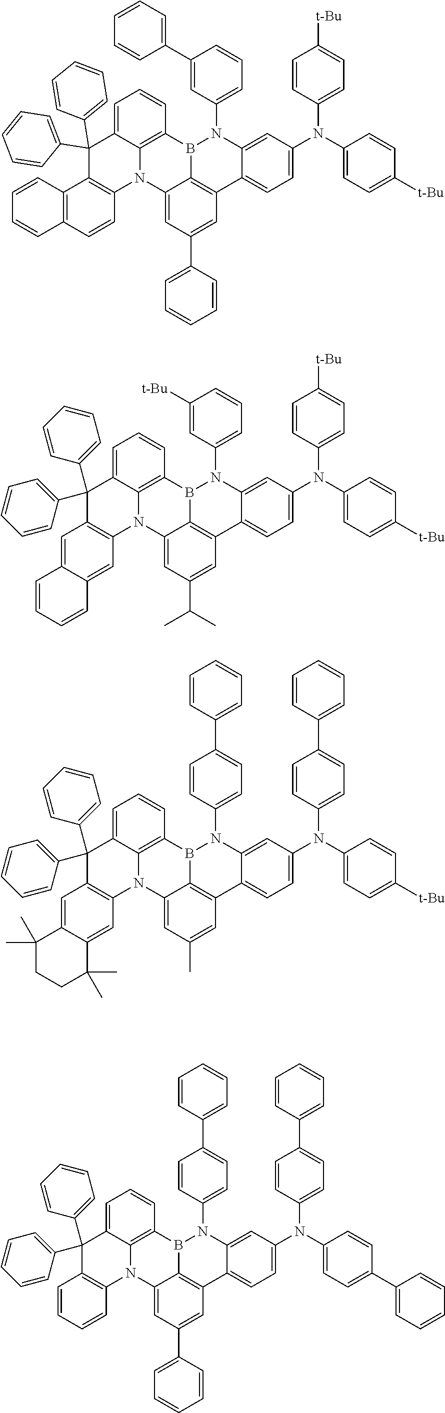

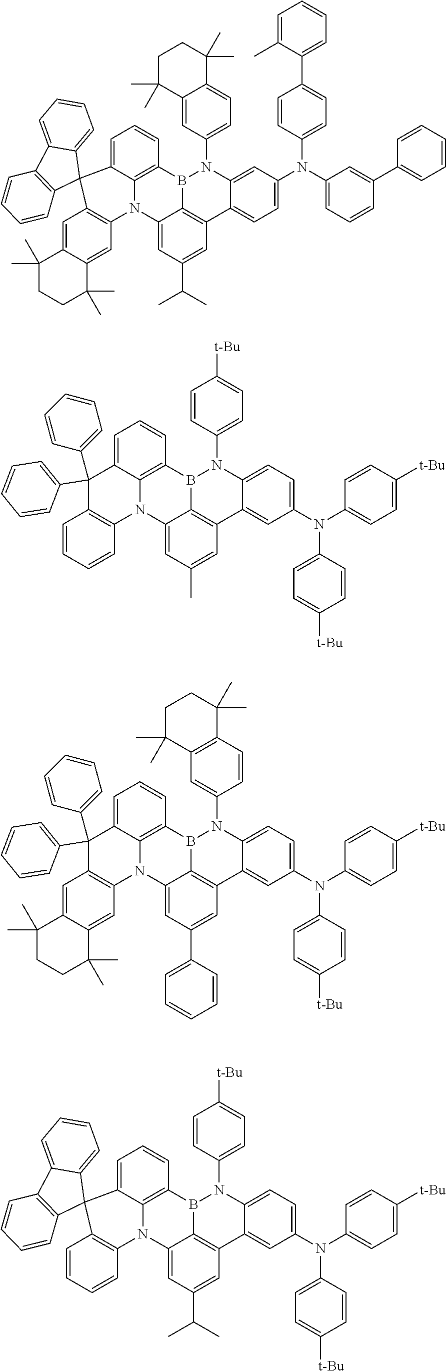

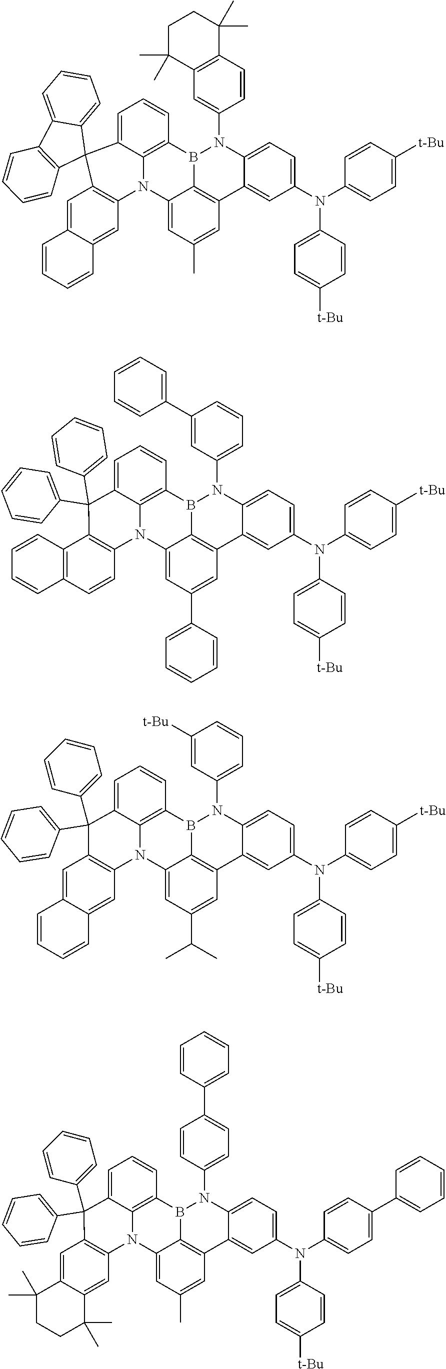

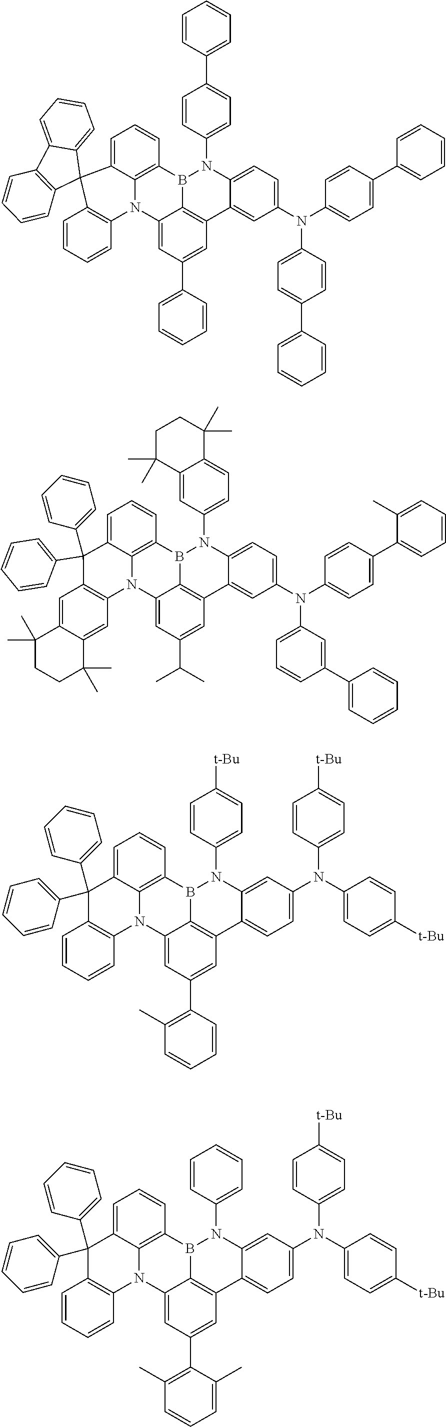

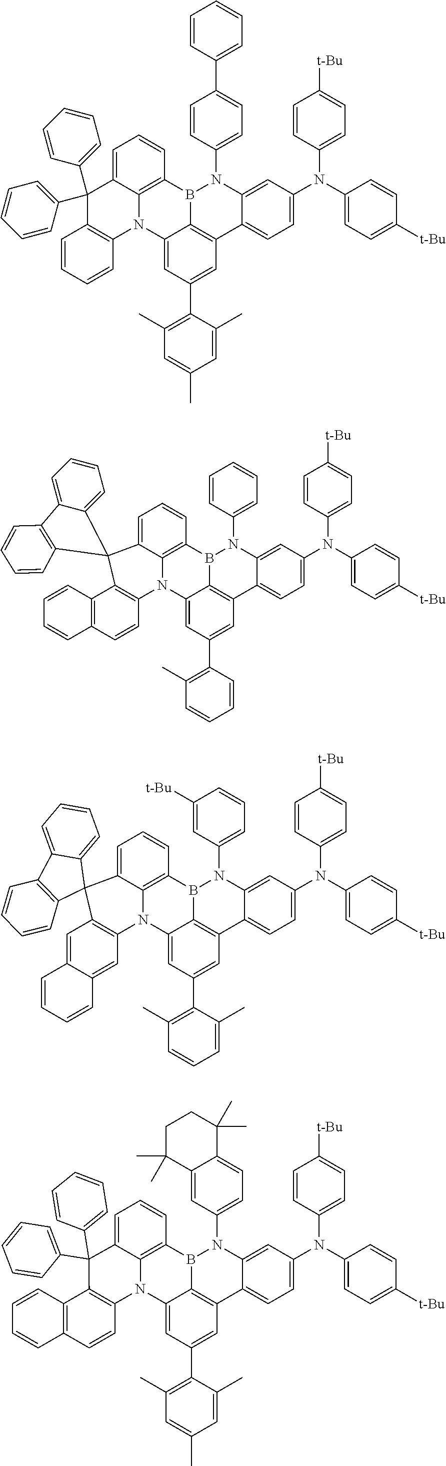

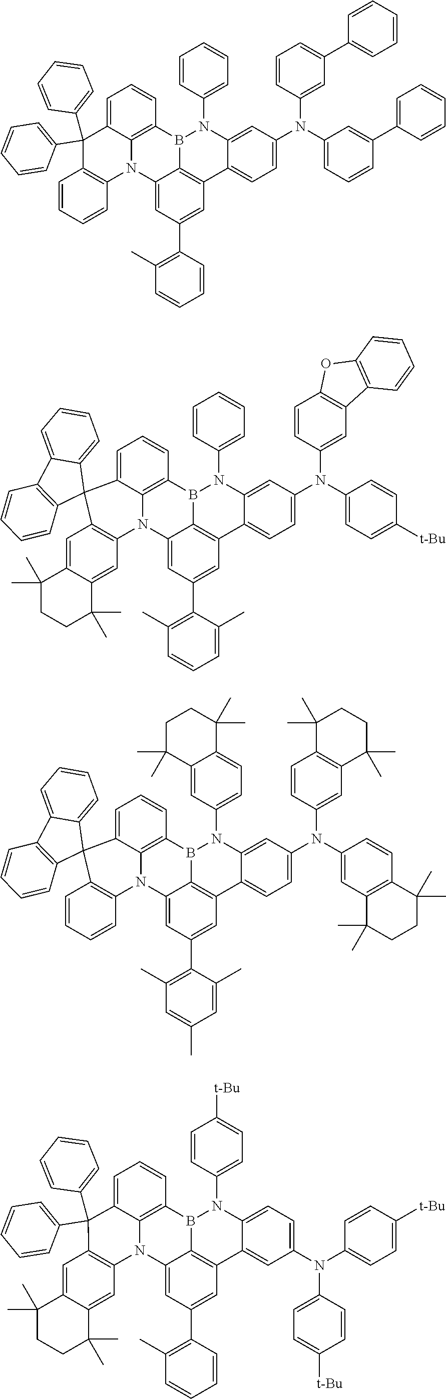

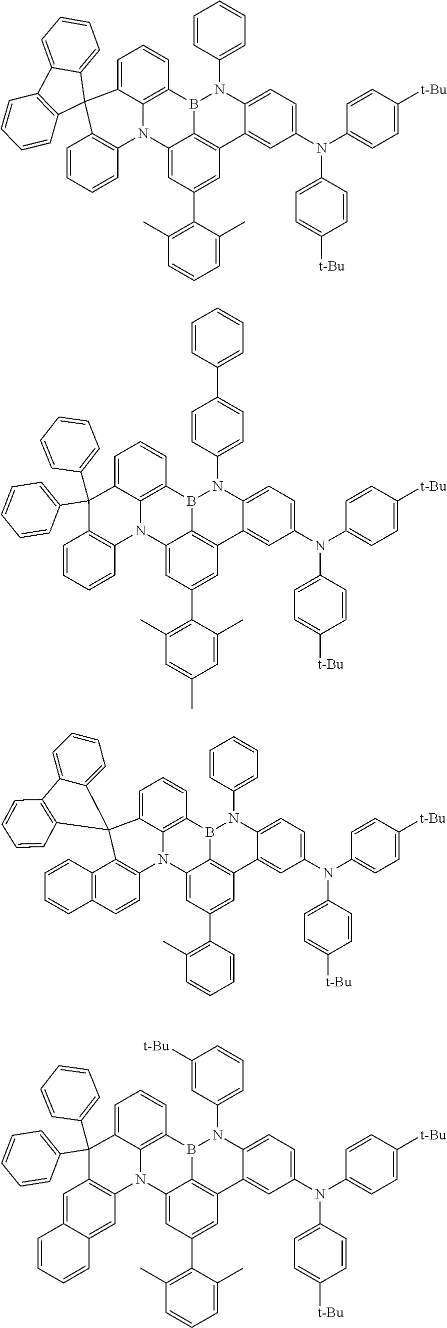

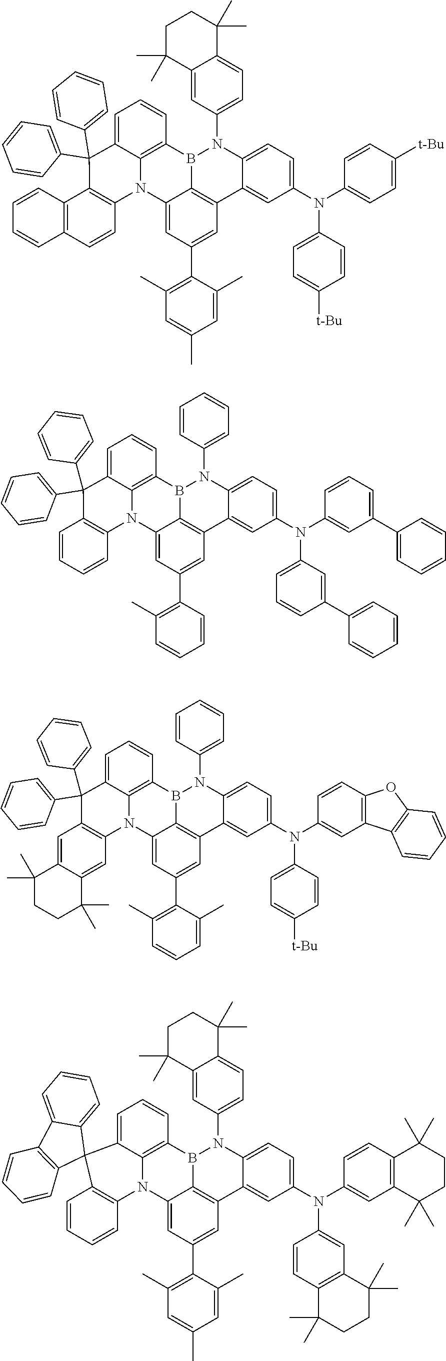

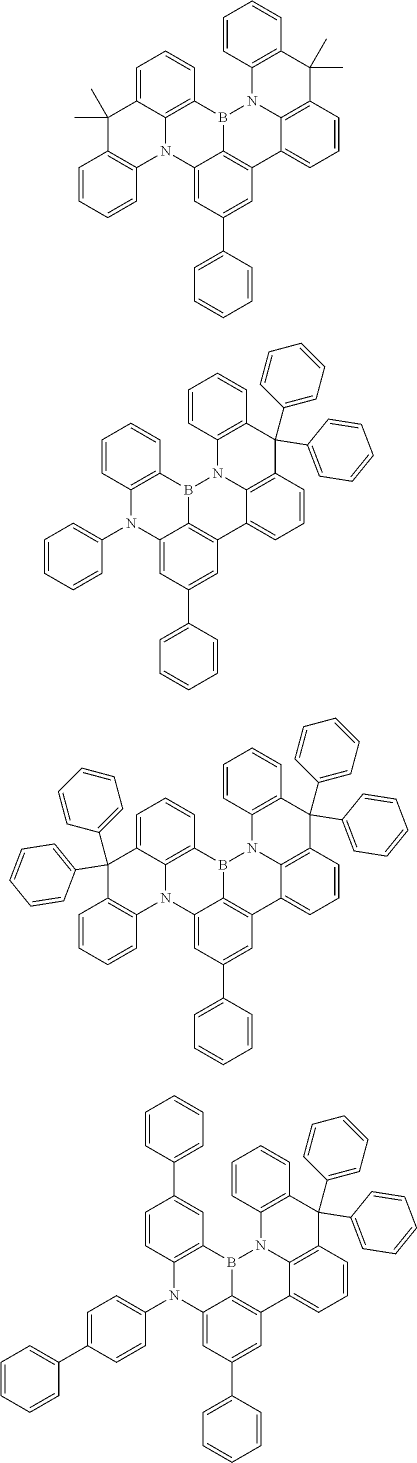

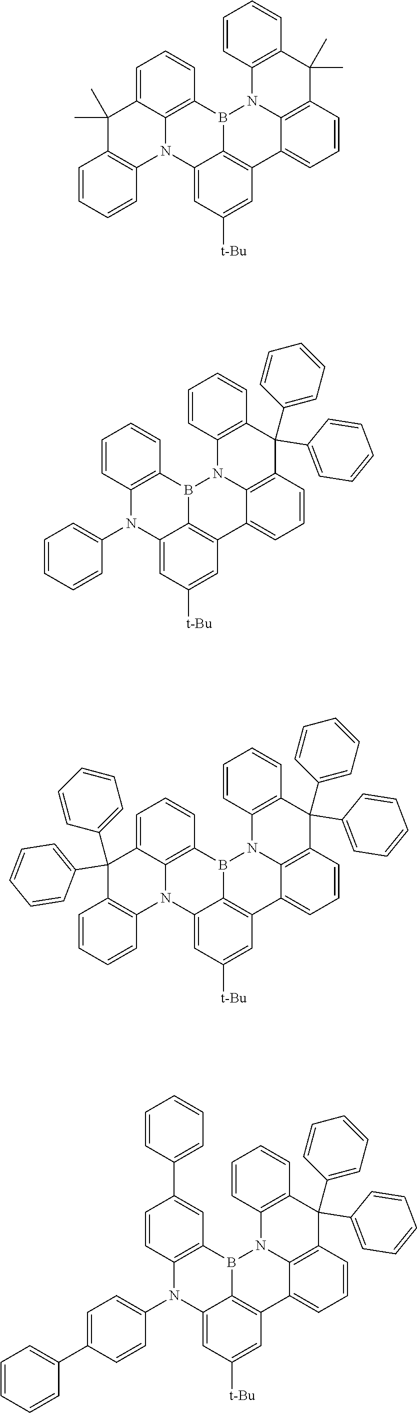

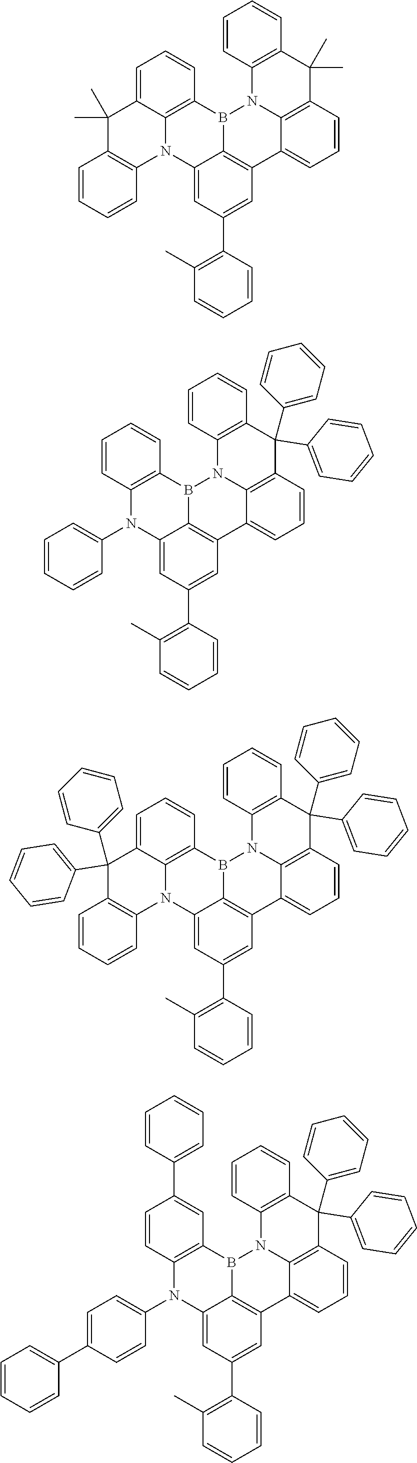

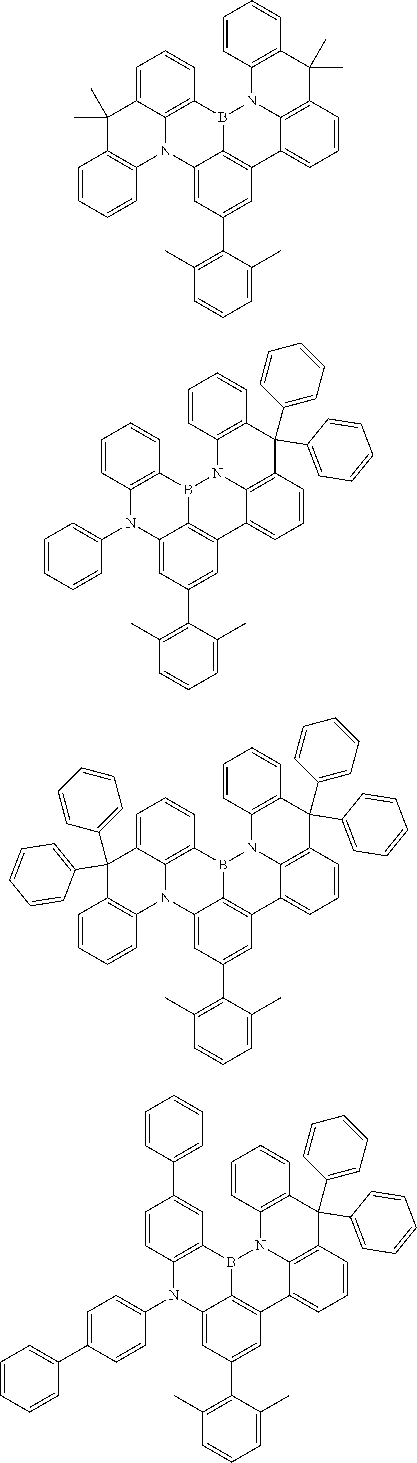

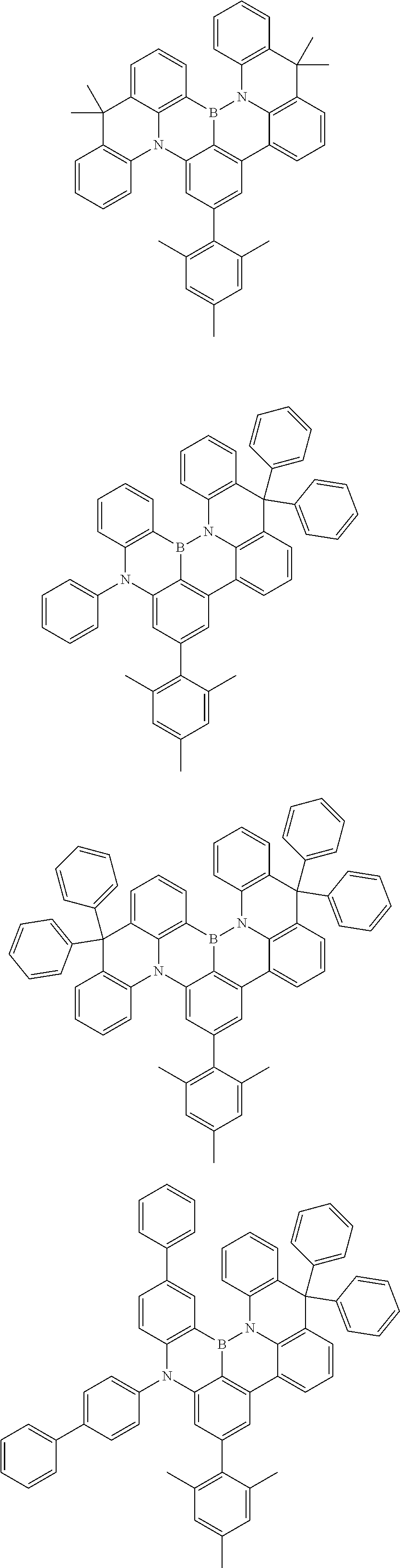

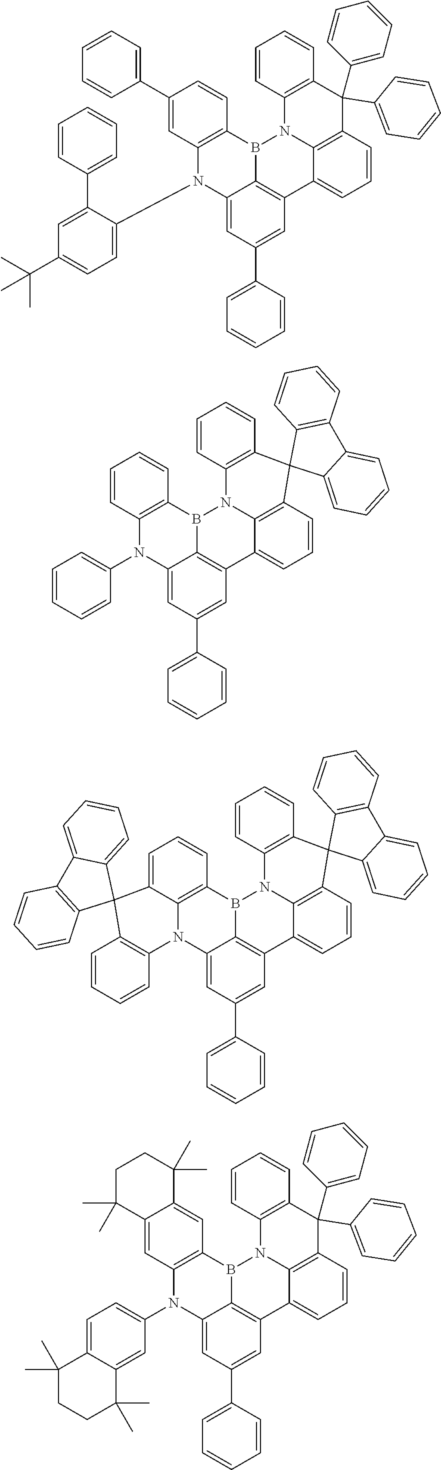

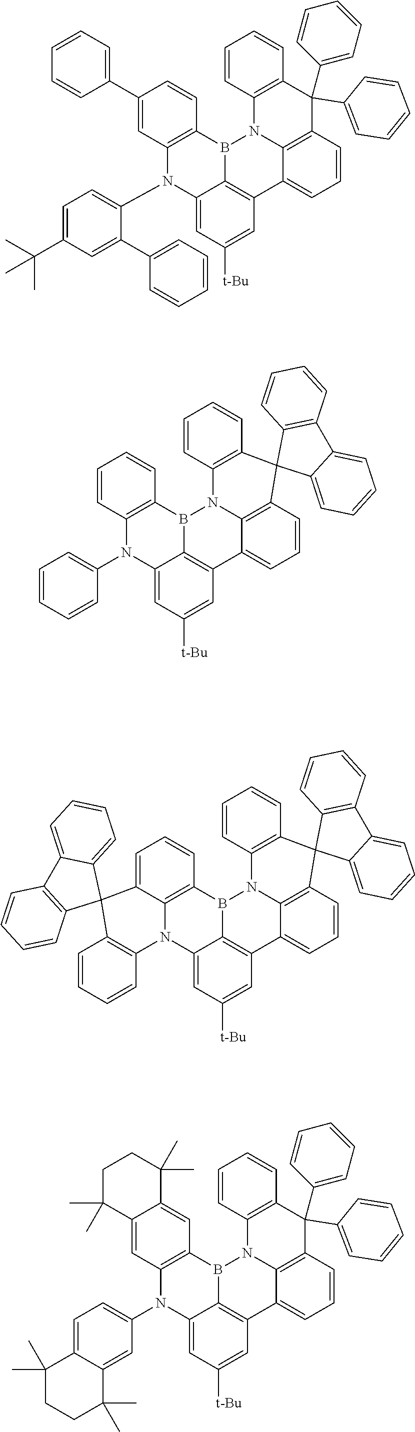 [SMILES: CC(C)(C)c1ccc(N2c3cc(-c4ccccc4)ccc3B3c4c(cc(C(C)(C)C)cc42)-c2cccc4c2N3c2ccccc2C4(c2ccccc2)c2ccccc2)c(-c2ccccc2)c1 ; CC(C)(C)c1cc2c3c(c1)N(c1ccccc1)c1ccccc1B3N1c3ccccc3C3(c4ccccc4-c4ccccc43)c3cccc-2c31 ; CC(C)(C)c1cc2c3c(c1)N1c4ccccc4C4(c5ccccc5-c5ccccc54)c4cccc(c41)B3N1c3ccccc3C3(c4ccccc4-c4ccccc43)c3cccc-2c31 ; CC(C)(C)c1cc2c3c(c1)N(c1ccc4c(c1)C(C)(C)CCC4(C)C)c1cc4c(cc1B3N1c3ccccc3C(c3ccccc3)(c3ccccc3)c3cccc-2c31)C(C)(C)CCC4(C)C]

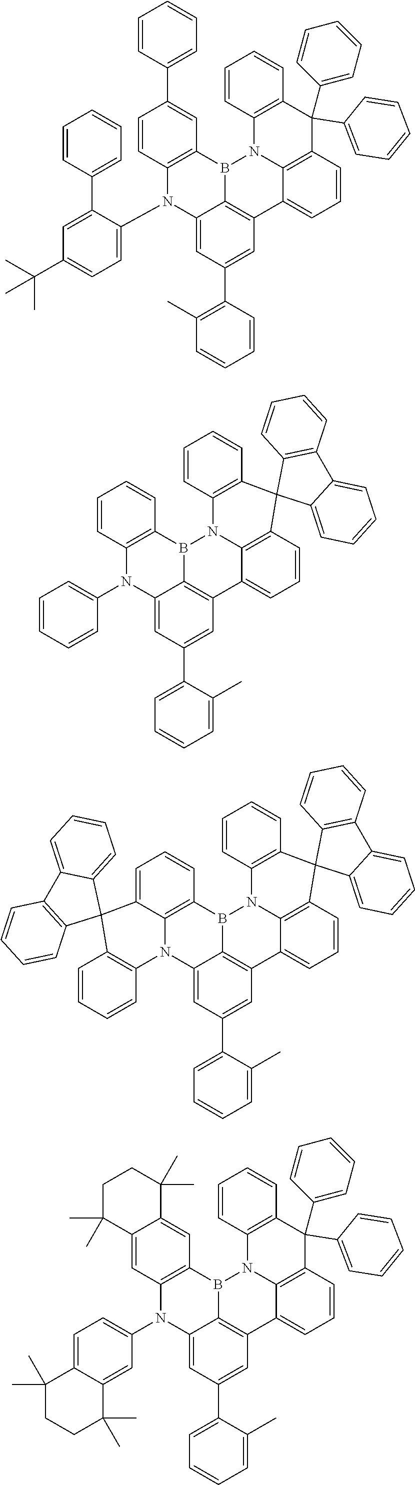 [SMILES: Cc1ccccc1-c1cc2c3c(c1)N(c1ccc(C(C)(C)C)cc1-c1ccccc1)c1ccc(-c4ccccc4)cc1B3N1c3ccccc3C(c3ccccc3)(c3ccccc3)c3cccc-2c31 ; Cc1ccccc1-c1cc2c3c(c1)N(c1ccccc1)c1ccccc1B3N1c3ccccc3C3(c4ccccc4-c4ccccc43)c3cccc-2c31 ; Cc1ccccc1-c1cc2c3c(c1)N1c4ccccc4C4(c5ccccc5-c5ccccc54)c4cccc(c41)B3N1c3ccccc3C3(c4ccccc4-c4ccccc43)c3cccc-2c31 ; Cc1ccccc1-c1cc2c3c(c1)N(c1ccc4c(c1)C(C)(C)CCC4(C)C)c1cc4c(cc1B3N1c3ccccc3C(c3ccccc3)(c3ccccc3)c3cccc-2c31)C(C)(C)CCC4(C)C]

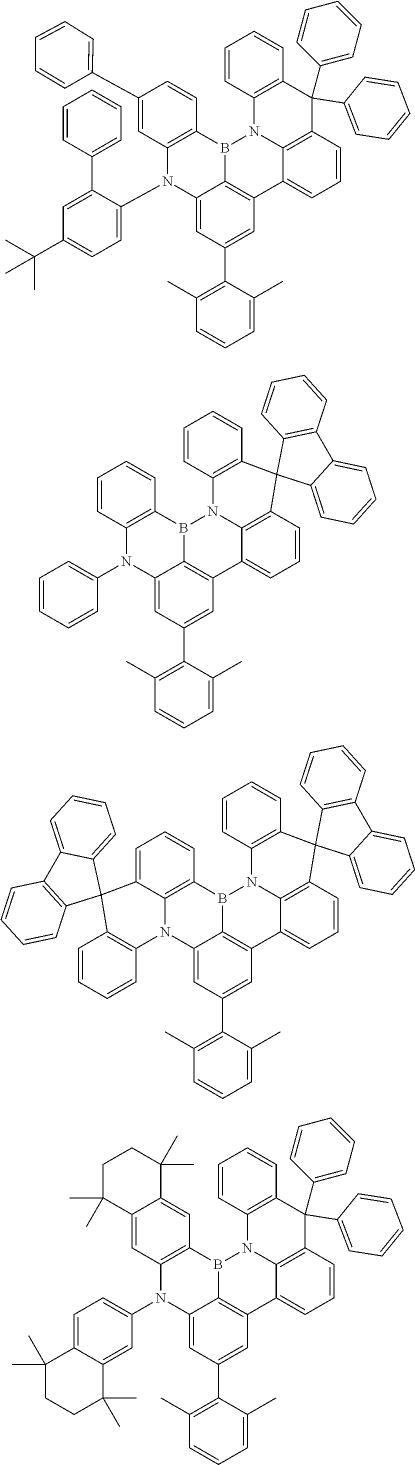 [SMILES: Cc1cccc(C)c1-c1cc2c3c(c1)N(c1ccc(C(C)(C)C)cc1-c1ccccc1)c1cc(-c4ccccc4)ccc1B3N1c3ccccc3C(c3ccccc3)(c3ccccc3)c3cccc-2c31 ; Cc1cccc(C)c1-c1cc2c3c(c1)N(c1ccccc1)c1ccccc1B3N1c3ccccc3C3(c4ccccc4-c4ccccc43)c3cccc-2c31 ; Cc1cccc(C)c1-c1cc2c3c(c1)N1c4ccccc4C4(c5ccccc5-c5ccccc54)c4cccc(c41)B3N1c3ccccc3C3(c4ccccc4-c4ccccc43)c3cccc-2c31 ; Cc1cccc(C)c1-c1cc2c3c(c1)N(c1ccc4c(c1)C(C)(C)CCC4(C)C)c1cc4c(cc1B3N1c3ccccc3C(c3ccccc3)(c3ccccc3)c3cccc-2c31)C(C)(C)CCC4(C)C]

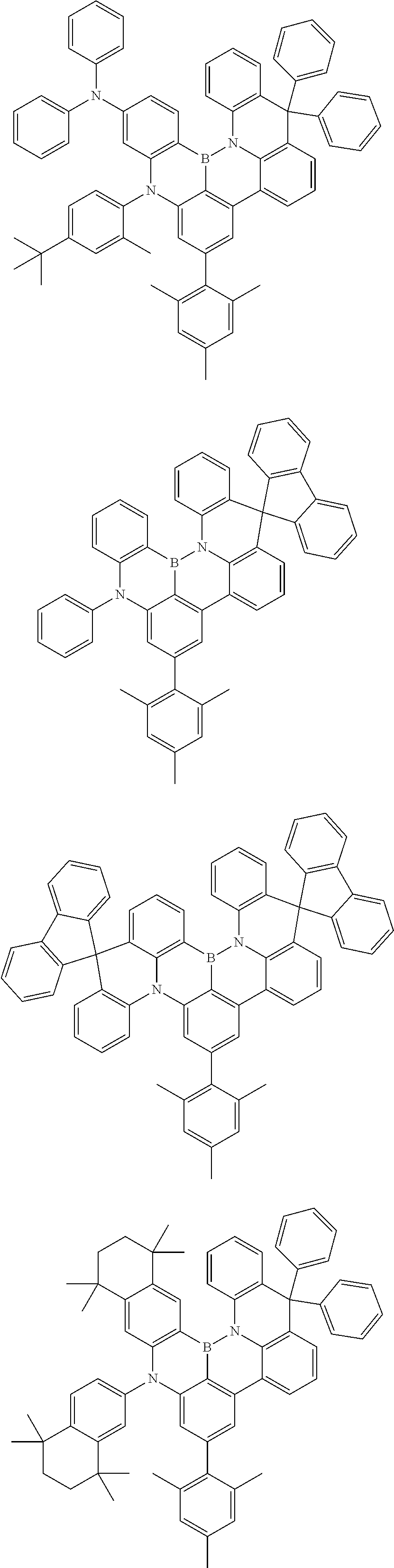 [SMILES: Cc1cc(C)c(-c2cc3c4c(c2)N(c2ccc(C(C)(C)C)cc2C)c2cc(N(c5ccccc5)c5ccccc5)ccc2B4N2c4ccccc4C(c4ccccc4)(c4ccccc4)c4cccc-3c42)c(C)c1 ; Cc1cc(C)c(-c2cc3c4c(c2)N(c2ccccc2)c2ccccc2B4N2c4ccccc4C4(c5ccccc5-c5ccccc54)c4cccc-3c42)c(C)c1 ; Cc1cc(C)c(-c2cc3c4c(c2)N2c5ccccc5C5(c6ccccc6-c6ccccc65)c5cccc(c52)B4N2c4ccccc4C4(c5ccccc5-c5ccccc54)c4cccc-3c42)c(C)c1 ; Cc1cc(C)c(-c2cc3c4c(c2)N(c2ccc5c(c2)C(C)(C)CCC5(C)C)c2cc5c(cc2B4N2c4ccccc4C(c4ccccc4)(c4ccccc4)c4cccc-3c42)C(C)(C)CCC5(C)C)c(C)c1]

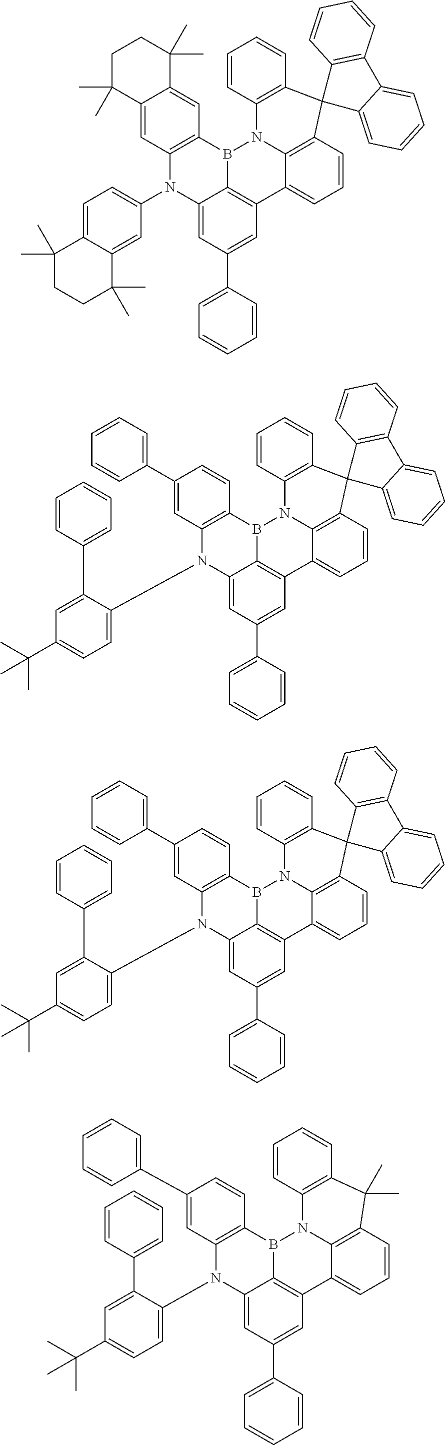 [SMILES: CC1(C)CCC(C)(C)c2cc(N3c4cc5c(cc4B4c6c(cc(-c7ccccc7)cc63)-c3cccc6c3N4c3ccccc3C63c4ccccc4-c4ccccc43)C(C)(C)CCC5(C)C)ccc21 ; CC(C)(C)c1ccc(N2c3cc(-c4ccccc4)ccc3B3c4c(cc(-c5ccccc5)cc42)-c2cccc4c2N3c2ccccc2C42c3ccccc3-c3ccccc32)c(-c2ccccc2)c1 ; CC(C)(C)c1ccc(N2c3cc(-c4ccccc4)ccc3B3c4c(cc(-c5ccccc5)cc42)-c2cccc4c2N3c2ccccc2C42c3ccccc3-c3ccccc32)c(-c2ccccc2)c1 ; CC(C)(C)c1ccc(N2c3cc(-c4ccccc4)ccc3B3c4c(cc(-c5ccccc5)cc42)-c2cccc4c2N3c2ccccc2C4(C)C)c(-c2ccccc2)c1]

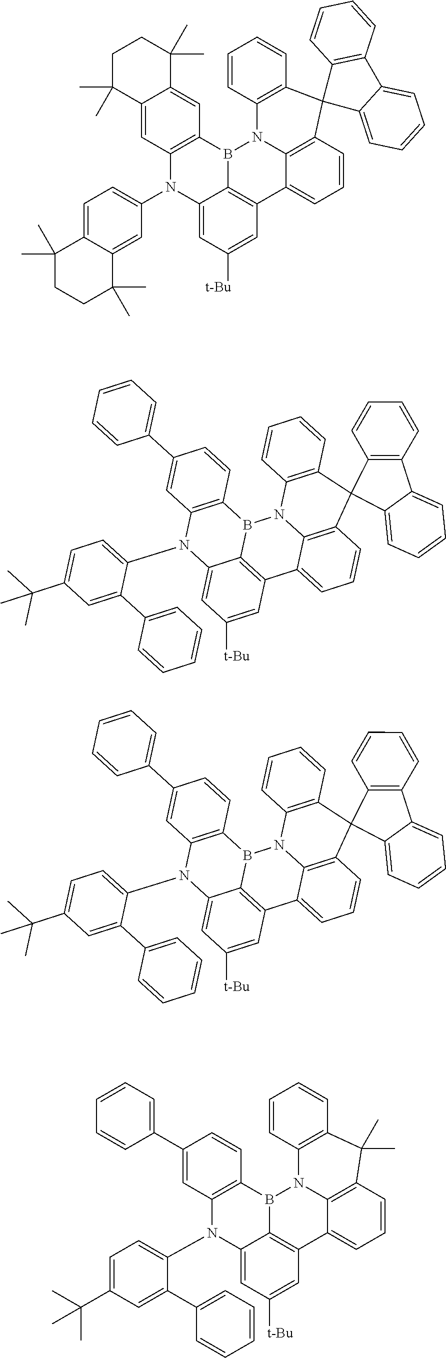 [SMILES: CC(C)(C)c1cc2c3c(c1)N(c1ccc4c(c1)C(C)(C)CCC4(C)C)c1cc4c(cc1B3N1c3ccccc3C3(c5ccccc5-c5ccccc53)c3cccc-2c31)C(C)(C)CCC4(C)C ; CC(C)(C)c1ccc(N2c3cc(-c4ccccc4)ccc3B3c4c(cc(C(C)(C)C)cc42)-c2cccc4c2N3c2ccccc2C42c3ccccc3-c3ccccc32)c(-c2ccccc2)c1 ; CC(C)(C)c1ccc(N2c3cc(-c4ccccc4)ccc3B3c4c(cc(C(C)(C)C)cc42)-c2cccc4c2N3c2ccccc2C42c3ccccc3-c3ccccc32)c(-c2ccccc2)c1 ; CC(C)(C)c1ccc(N2c3cc(-c4ccccc4)ccc3B3c4c(cc(C(C)(C)C)cc42)-c2cccc4c2N3c2ccccc2C4(C)C)c(-c2ccccc2)c1]

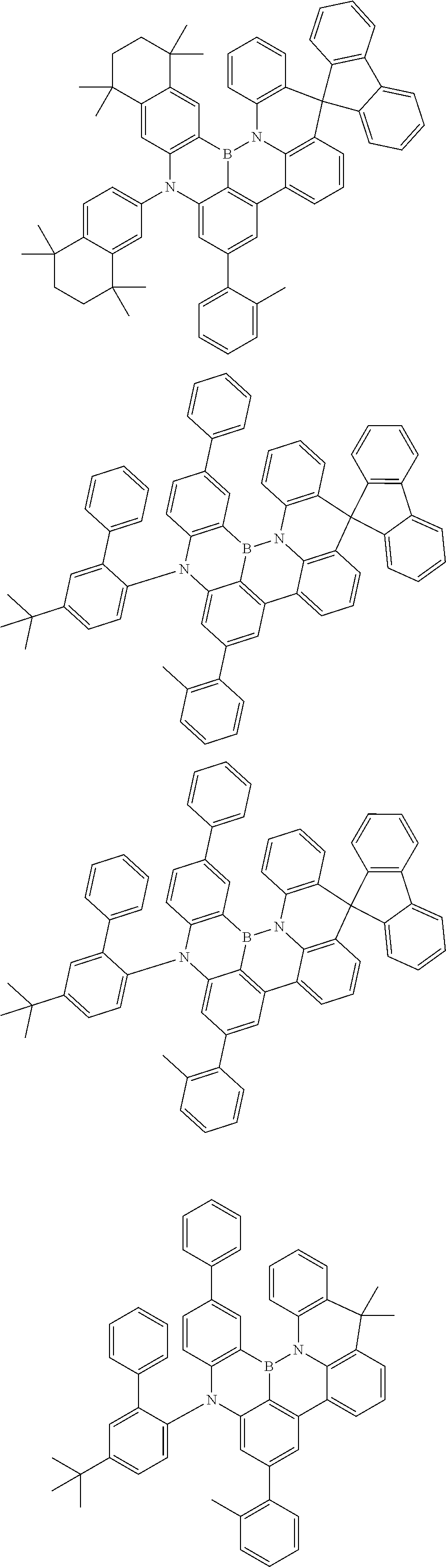

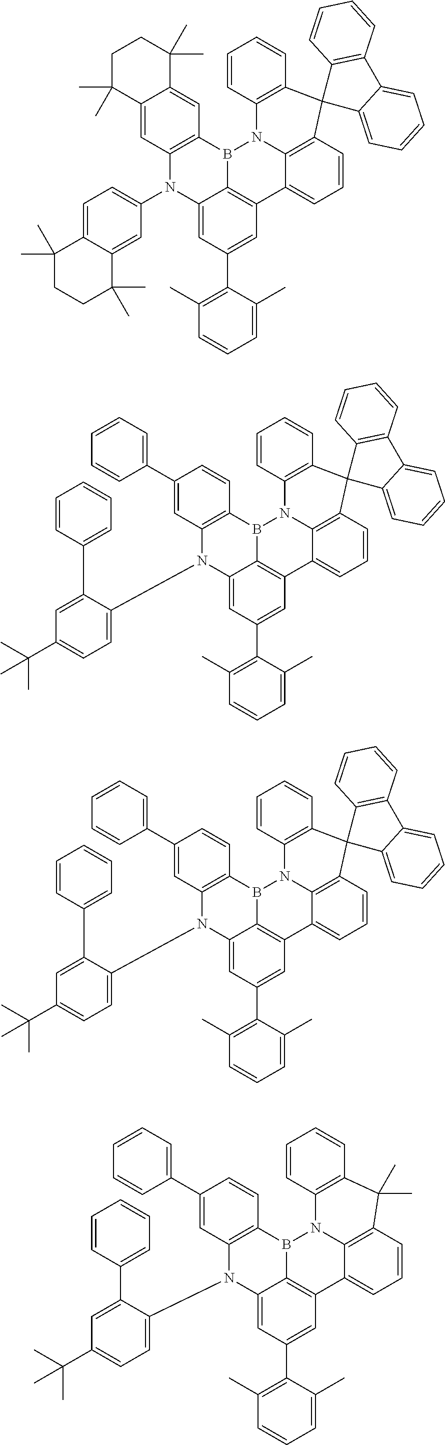 [SMILES: Cc1cccc(C)c1-c1cc2c3c(c1)N(c1ccc4c(c1)C(C)(C)CCC4(C)C)c1cc4c(cc1B3N1c3ccccc3C3(c5ccccc5-c5ccccc53)c3cccc-2c31)C(C)(C)CCC4(C)C ; Cc1cccc(C)c1-c1cc2c3c(c1)N(c1ccc(C(C)(C)C)cc1-c1ccccc1)c1cc(-c4ccccc4)ccc1B3N1c3ccccc3C3(c4ccccc4-c4ccccc43)c3cccc-2c31 ; Cc1cccc(C)c1-c1cc2c3c(c1)N(c1ccc(C(C)(C)C)cc1-c1ccccc1)c1cc(-c4ccccc4)ccc1B3N1c3ccccc3C3(c4ccccc4-c4ccccc43)c3cccc-2c31 ; Cc1cccc(C)c1-c1cc2c3c(c1)N(c1ccc(C(C)(C)C)cc1-c1ccccc1)c1cc(-c4ccccc4)ccc1B3N1c3ccccc3C(C)(C)c3cccc-2c31]

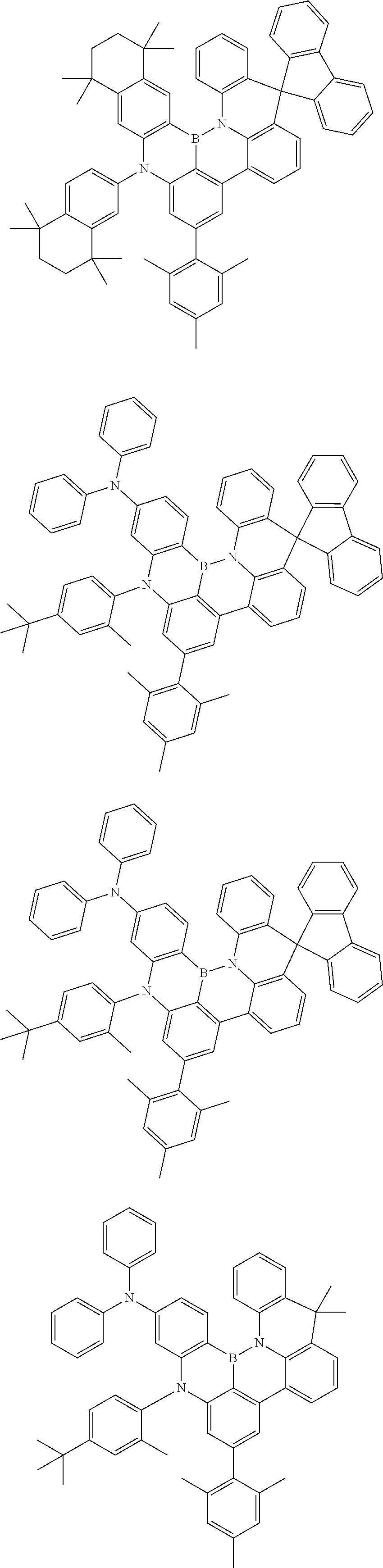

The same equivalents and method were used as in the synthesis process of Int134 using 3-bromo-1-chlorodibenzo[b,d]furan and 9,9-dimethyl-N-(3,5,5,8,8-pentamethyl-5,6,7,8-tetrahydronaphthalen-2-yl)-9H-fluoren-4-amine instead of 2-bromo-4-chlorodibenzo[b,d]furan and di([1,1′-biphenyl]-4-yl)amine, and after the reaction was finished, the result was extracted and then recrystallized to obtain Int196 (47.2 g, yield 73%). MS[M+H]+=611

### 2) Synthesis of Int197

The same equivalents and method were used as in the synthesis process of Int135 using Int196 and 4-(4,4,5,5-tetramethyl-1,3,2-dioxaborolan-2-yl)-3-((5,5,8,8-tetramethyl-5,6,7,8-tetrahydronaphthalen-2-yl)amino)phenol instead of Int134 and 3,6-di-tert-butyl-1-(4,4,5,5-tetramethyl-1,3,2-dioxaborolan-2-yl)-9H-carbazole, and after the reaction was finished, the result was extracted and then recrystallized to obtain Int197 (33.1 g, yield 77%). MS[M+H]+=870

### 3) Synthesis of Int198

Under the nitrogen atmosphere, Int197 (25 g) and boron triiodide (19.2 g) were introduced to 1,2-dichlorobenzene (250 ml), and stirred for 4 hours at 160° C. After the reaction was finished, the result was extracted, and then recrystallized to obtain Int198 (7.2 g, yield 29%). MS[M+H]+=878

### 4) Synthesis of Int199

Int198 (7 g), 1,1,2,2,3,3,4,4,4-nonafluorobutane-1-sulfonyl fluoride (2.2 ml) and potassium carbonate (3.3 g) were introduced to tetrahydrofuran (70 ml) and water (30 ml), and stirred for 2 hours under reflux. After the reaction was finished, the result was extracted, and then column purified to obtain Int199 (8.8 g, yield 95%). MS[M+H]+=1160

5) Synthesis of Compound M99 Under the nitrogen atmosphere, Int199 (7 g), bis(4-(tert-butyl)phenyl)amine (1.7 g), pd(dba)₂ (0.11 g), Xphos (0.18 g) and cesium carbonate (6.0 g) were introduced to xylene (100 ml), and stirred for 12 hours under reflux. After the reaction was finished, the result was extracted, and then recrystallized to obtain Compound M99 (5.4 g, yield 78%). MS[M+H]+=1141

### Synthesis Example 100. Synthesis of Compound M100

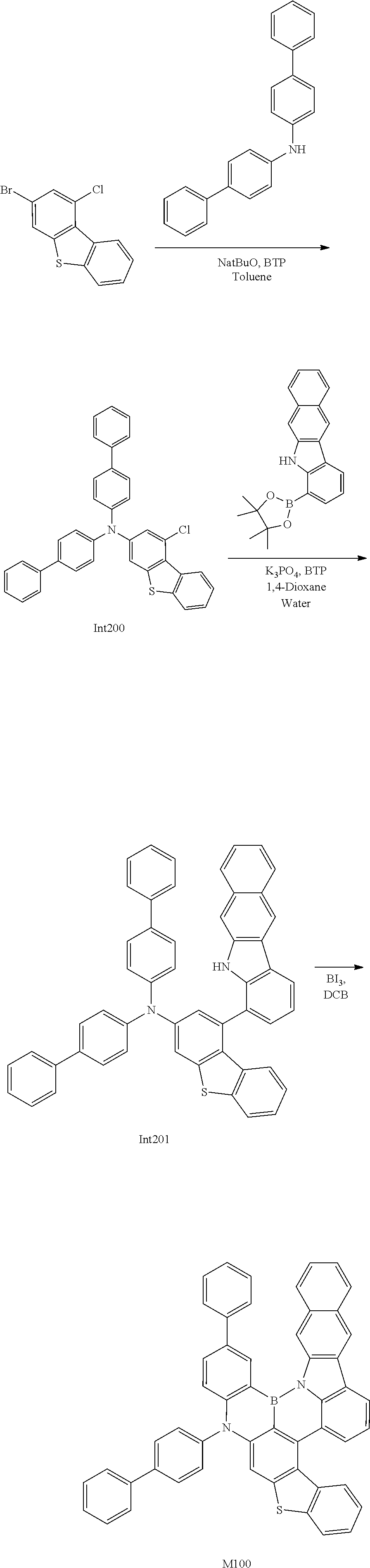

### 1) Synthesis of Int200

The same equivalents and method were used as in the synthesis process of Int134 using 3-bromo-1-chlorodibenzo[b,d]thiophene instead of 2-bromo-4-chlorodibenzo[b, d]furan, and after the reaction was finished, the result was extracted and then recrystallized to obtain Int200 (41.4 g, yield 72%). MS[M+H]+=539

### 2) Synthesis of Int201

The same equivalents and method were used as in the synthesis process of Int135 using Int200 and 4-(4,4,5,5-tetramethyl-1,3,2-dioxaborolan-2-yl)-5H-benzo[b]carbazole instead of Int134 and 3,6-di-tert-butyl-1-(4,4,5,5-tetramethyl-1,3,2-dioxaborolan-2-yl)-9H-carbazole, and after the reaction was finished, the result was extracted and then recrystallized to obtain Int201 (28.8 g, yield 72%). MS [M+H]+=720

### 3) Synthesis of Compound M100

Under the nitrogen atmosphere, Int201 (25 g) and boron triiodide (23.1 g) were introduced to 1,2-dichlorobenzene (250 ml), and stirred for 4 hours at 160° C. After the reaction was finished, the result was extracted, and then recrystallized to obtain Compound M100 (7.6 g, yield 30%). MS[M+H]+=728

### Synthesis Example 101. Synthesis of Compound M101

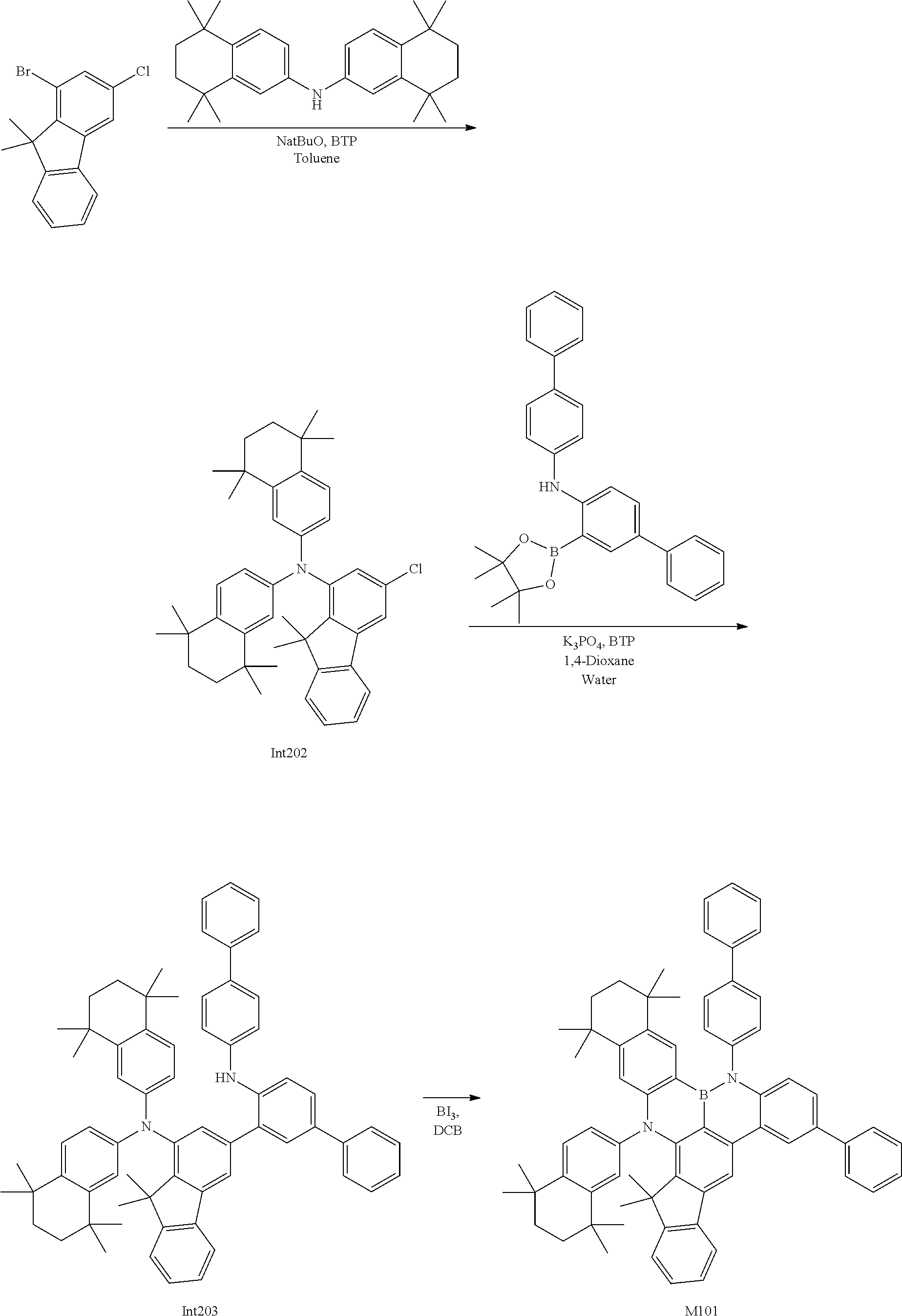

### 1) Synthesis of Int202

The same equivalents and method were used as in the synthesis process of Int134 using 1-bromo-3-chloro-9,9-dimethyl-9H-fluorene and bis(5,5,8,8-tetramethyl-5,6,7,8-tetrahydronaphthalen-2-yl)amine instead of 2-bromo-4-chlorodibenzo[b,d]furan and di([1,1′-biphenyl]-4-yl)amine, and after the reaction was finished, the result was extracted and then recrystallized to obtain Int202 (43.3 g, yield 72%). MS [M+H]+=617

### 2) Synthesis of Int203

The same equivalents and method were used as in the synthesis process of Int135 using Int202 and N-([1,1′-biphenyl]-4-yl)-3-(4,4,5,5-tetramethyl-1,3,2-dioxaborolan-2-yl)-[1,1′-biphenyl]-4-amine instead of Int134 and 3,6-di-tert-butyl-1-(4,4,5,5-tetramethyl-1,3,2-dioxaborolan-2-yl)-9H-carbazole, and after the reaction was finished, the result was extracted and then recrystallized to obtain Int203 (34.3 g, yield 78%). MS[M+H]+=902

### 3) Synthesis of Compound M101

Under the nitrogen atmosphere, Int203 (25 g) and boron triiodide (18.5 g) were introduced to 1,2-dichlorobenzene (250 ml), and stirred for 4 hours at 160° C. After the reaction was finished, the result was extracted, and then recrystallized to obtain Compound M101 (7.6 g, yield 30%). MS[M+H]+=910

### Synthesis Example 102. Synthesis of Compound M102

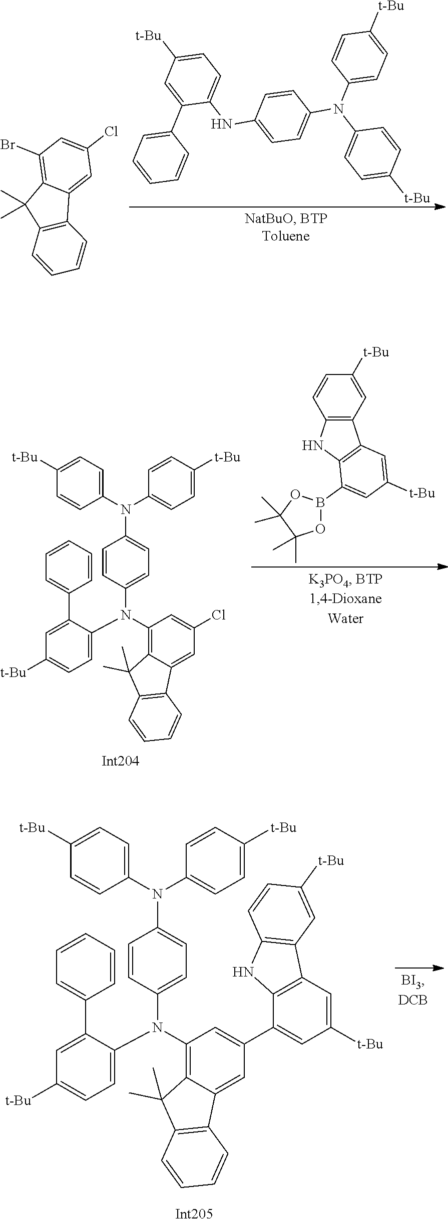

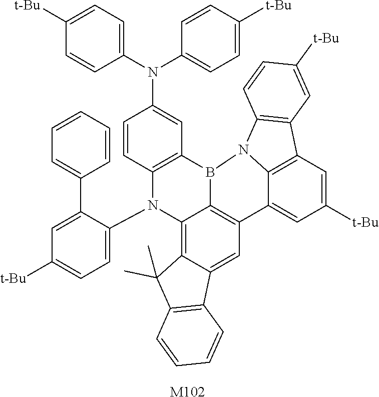

### 1) Synthesis of Int204

The same equivalents and method were used as in the synthesis process of Int134 using 1-bromo-3-chloro-9,9-dimethyl-9H-fluorene and N1-(5-(tert-butyl)-[1,1′-biphenyl]-2-yl)-N4,N4-bis(4-(tert-butyl)phenyl)benzene-1,4-diamine instead of 2-bromo-4-chlorodibenzo[b,d]furan and di([1,1′-biphenyl]-4-yl)amine, and after the reaction was finished, the result was extracted and then recrystallized to obtain Int204 (55.9 g, yield 71%). MS[M+H]+=809

### 2) Synthesis of Int205

The same equivalents and method were used as in the synthesis process of Int135 using Int204 instead of Int134, and after the reaction was finished, the result was extracted and then recrystallized to obtain Int205 (29.8 g, yield 76%). MS[M+H]+=1052

### 3) Synthesis of Compound M102

Under the nitrogen atmosphere, Int205 (25 g) and boron triiodide (15.8 g) were introduced to 1,2-dichlorobenzene (250 ml), and stirred for 4 hours at 160° C. After the reaction was finished, the result was extracted, and then recrystallized to obtain Compound M102 (7.4 g, yield 29%). MS[M+H]+=1060

### Synthesis Example 103. Synthesis of Compound M103

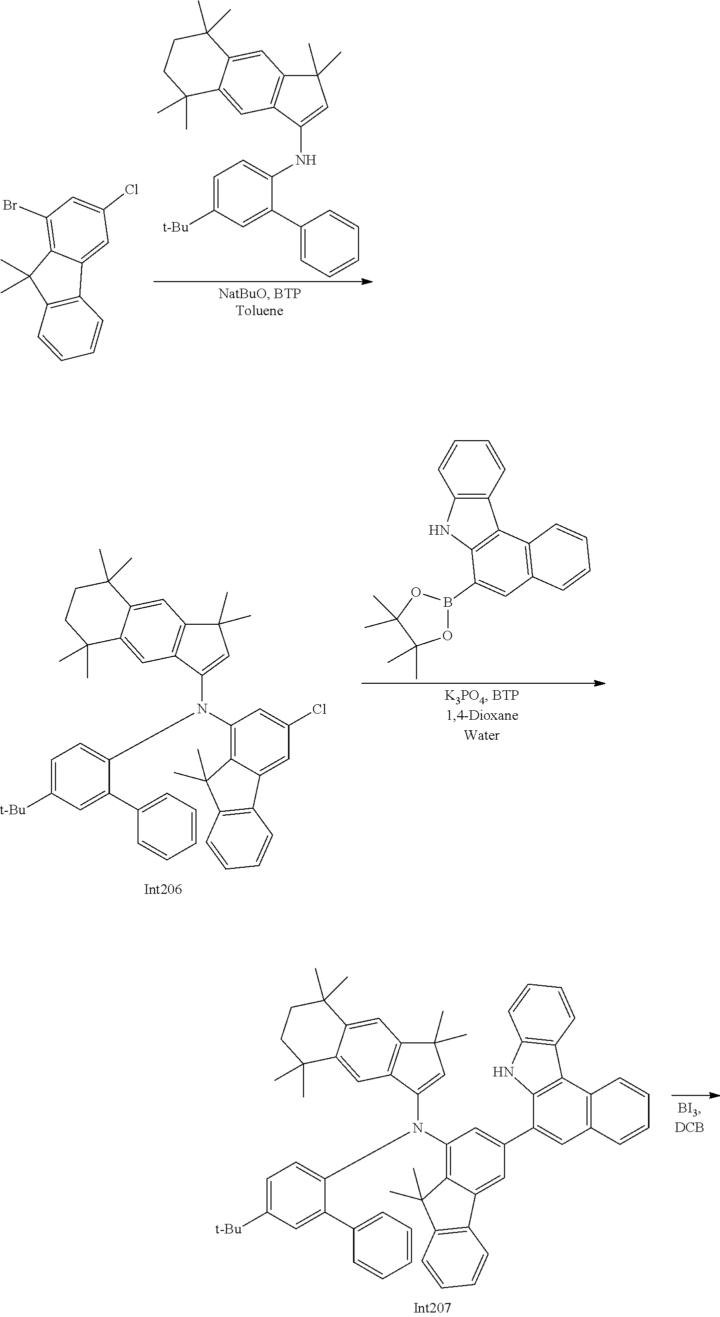 [SMILES: CC1(C)c2ccccc2-c2cc(Cl)cc(Br)c21 ; CC(C)(C)c1ccc(NC2=CC(C)(C)c3cc4c(cc32)C(C)(C)CCC4(C)C)c(-c2ccccc2)c1 ; CC(C)(C)c1ccc(N(C2=CC(C)(C)c3cc4c(cc32)C(C)(C)CCC4(C)C)c2cc(Cl)cc3c2C(C)(C)c2ccccc2-3)c(-c2ccccc2)c1 ; CC1(C)OB(c2cc3ccccc3c3c2[nH]c2ccccc23)OC1(C)C ; CC(C)(C)c1ccc(N(C2=CC(C)(C)c3cc4c(cc32)C(C)(C)CCC4(C)C)c2cc(-c3cc4ccccc4c4c3[nH]c3ccccc34)cc3c2C(C)(C)c2ccccc2-3)c(-c2ccccc2)c1]

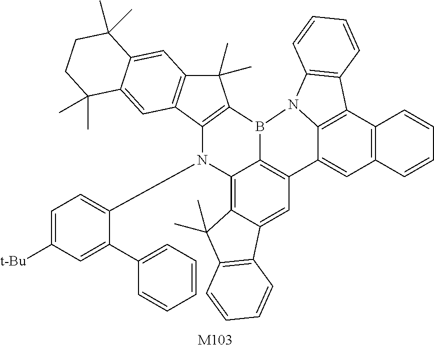

### 1) Synthesis of Int206

The same equivalents and method were used as in the synthesis process of Int134 using 1-bromo-3-chloro-9,9-dimethyl-9H-fluorene and N-(5-(tert-butyl)-[1,1′-biphenyl]-2-yl)-1,1,5,5,8,8-hexamethyl-5,6,7,8-tetrahydro-1H-cyclopenta[b]naphthalen-3-amine instead of 2-bromo-4-chlorodibenzo[b,d]furan and di([1,1′-biphenyl]-4-yl)amine, and after the reaction was finished, the result was extracted and then recrystallized to obtain Int206 (52 g, yield 76%). MS[M+H]+=705

### 2) Synthesis of Int207

The same equivalents and method were used as in the synthesis process of Int135 using Int206 and 6-(4,4,5,5-tetramethyl-1,3,2-dioxaborolan-2-yl)-7H-benzo[c]carbazole instead of Int134 and 3,6-di-tert-butyl-1-(4,4,5,5-tetramethyl-1,3,2-dioxaborolan-2-yl)-9H-carbazole, and after the reaction was finished, the result was extracted and then recrystallized to obtain Int207 (27.7 g, yield 73%). MS [M+H]+=886

### 3) Synthesis of Compound M103

Under the nitrogen atmosphere, Int207 (25 g) and boron triiodide (18.8 g) were introduced to 1,2-dichlorobenzene (250 ml), and stirred for 4 hours at 160° C. After the reaction was finished, the result was extracted, and then recrystallized to obtain Compound M103 (7.5 g, yield 30%). MS[M+H]+=894

### Synthesis Example 104. Synthesis of Compound M104

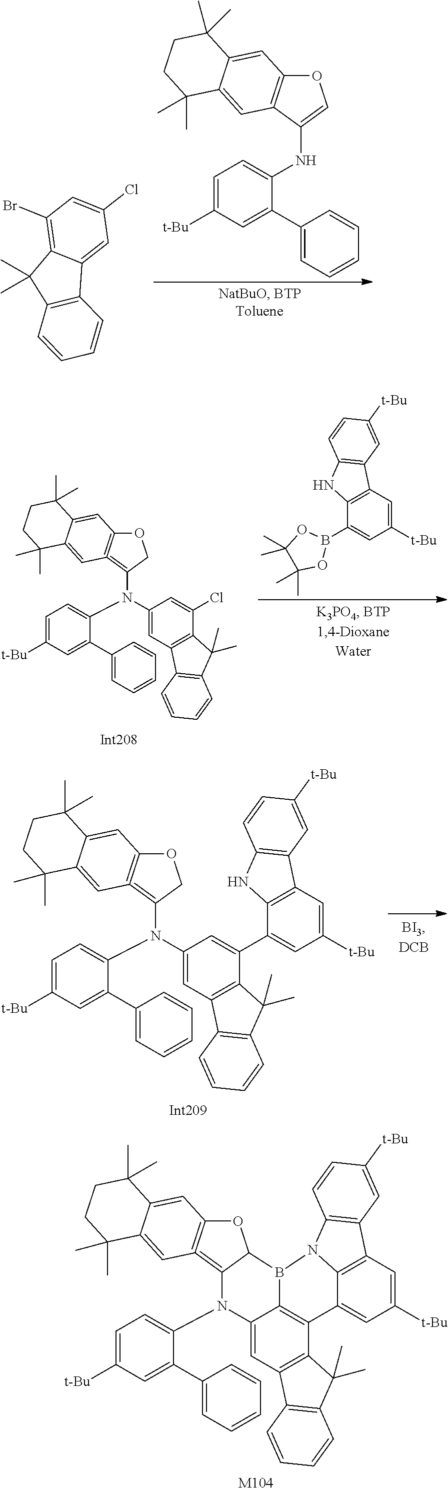

### 1) Synthesis of Int208

The same equivalents and method were used as in the synthesis process of Int134 using 3-bromo-1-chloro-9,9-dimethyl-9H-fluorene and N-(5-(tert-butyl)-[1,1′-biphenyl]-2-yl)-5,5,8,8-tetramethyl-5,6,7,8-tetrahydronaphtho[2,3-b]furan-3-amine instead of 2-bromo-4-chlorodibenzo[b,d]furan and di([1,1′-biphenyl]-4-yl)amine, and after the reaction was finished, the result was extracted and then recrystallized to obtain Int208 (51 g, yield 77%). MS[M+H]+=679

### 2) Synthesis of Int209

The same equivalents and method were used as in the synthesis process of Int135 using Int208 instead of Int134, and after the reaction was finished, the result was extracted and then recrystallized to obtain Int209 (31.4 g, yield 77%). MS[M+H]+=922

### 3) Synthesis of Compound M104

Under the nitrogen atmosphere, Int209 (25 g) and boron triiodide (18.1 g) were introduced to 1,2-dichlorobenzene (250 ml), and stirred for 4 hours at 160° C. After the reaction was finished, the result was extracted, and then recrystallized to obtain Compound M104 (7.3 g, yield 29%). MS[M+H]+=930

### Synthesis Example 105. Synthesis of Compound M105

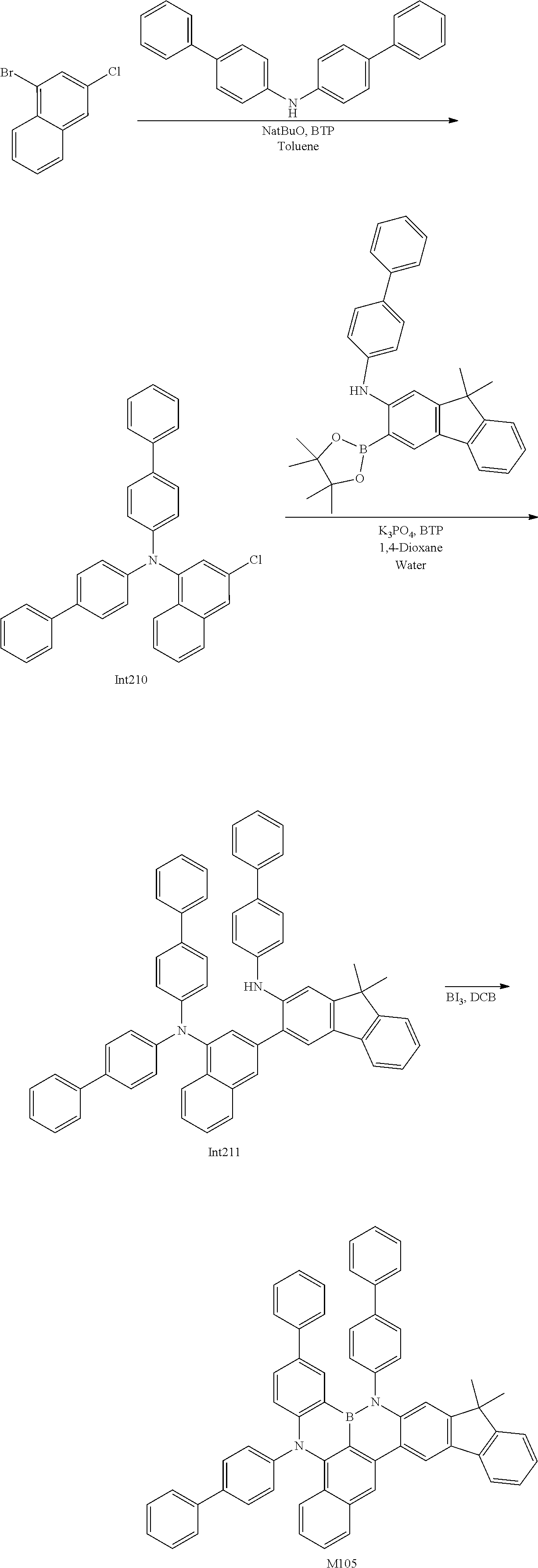

### 1) Synthesis of Int210

The same equivalents and method were used as in the synthesis process of Int134 using 1-bromo-3-chloronaphthalene instead of 2-bromo-4-chlorodibenzo[b,d]furan, and after the reaction was finished, the result was extracted and then recrystallized to obtain Int210 (43 g, yield 72%). MS[M+H]+=483

### 2) Synthesis of Int211

The same equivalents and method were used as in the synthesis process of Int135 using Int210 and N-([1,1′-biphenyl]-4-yl)-9,9-dimethyl-3-(4,4,5,5-tetramethyl-1,3,2-dioxaborolan-2-yl)-9H-fluoren-2-amine instead of Int134 and 3,6-di-tert-butyl-1-(4,4,5,5-tetramethyl-1,3,2-dioxaborolan-2-yl)-9H-carbazole, and after the reaction was finished, the result was extracted and then recrystallized to obtain Int211 (36.6 g, yield 73%). MS[M+H]+=808

3) Synthesis of Compound M105 Under the nitrogen atmosphere, Int211 (25 g) and boron triiodide (20.6 g) were introduced to 1,2-dichlorobenzene (250 ml), and stirred for 4 hours at 160° C. After the reaction was finished, the result was extracted, and then recrystallized to obtain Compound M105 (7.2 g, yield 29%). MS[M+H]+=816

### Synthesis Example 106. Synthesis of Compound M106

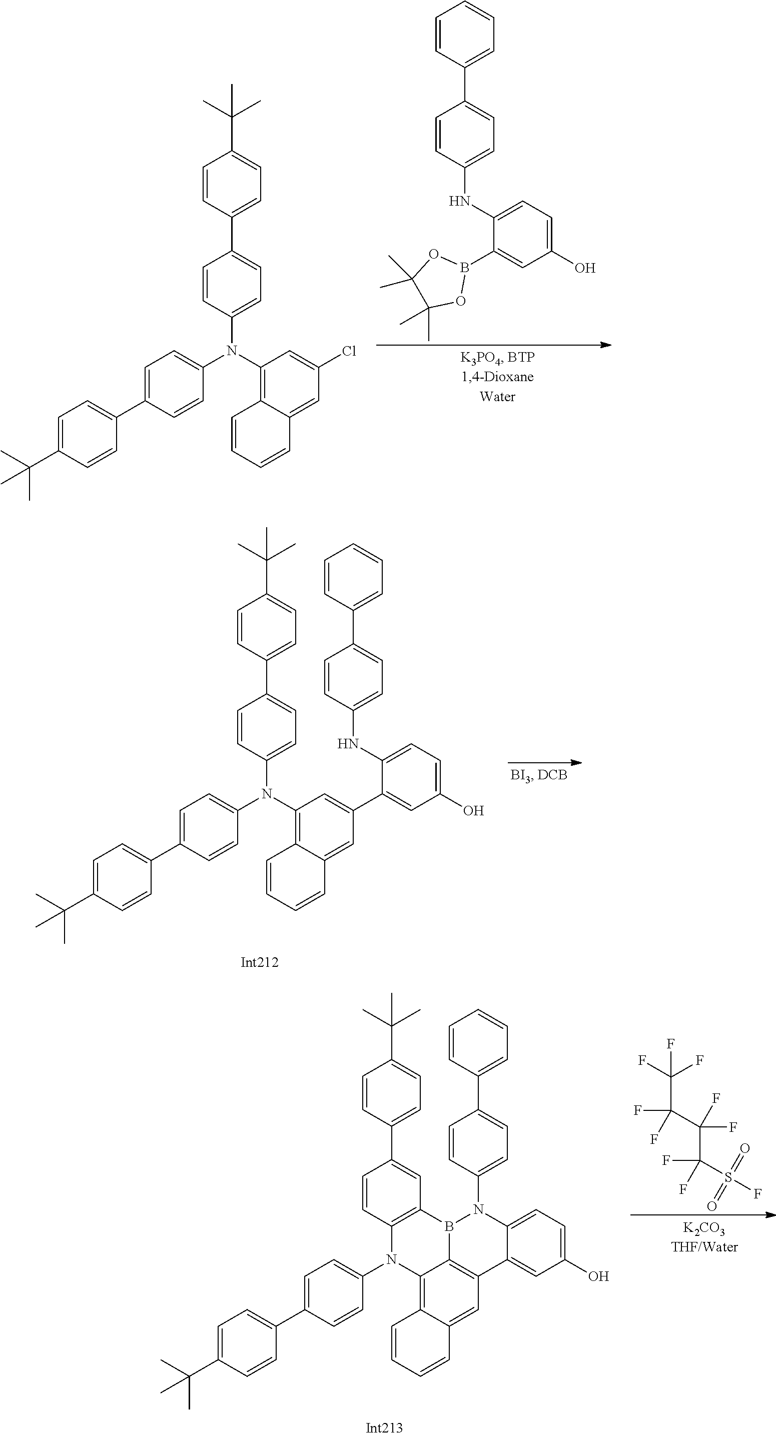 [SMILES: CC(C)(C)c1ccc(-c2ccc(N(c3ccc(-c4ccc(C(C)(C)C)cc4)cc3)c3cc(Cl)cc4ccccc34)cc2)cc1 ; CC1(C)OB(c2cc(O)ccc2Nc2ccc(-c3ccccc3)cc2)OC1(C)C ; CC(C)(C)c1ccc(-c2ccc(N(c3ccc(-c4ccc(C(C)(C)C)cc4)cc3)c3cc(-c4cc(O)ccc4Nc4ccc(-c5ccccc5)cc4)cc4ccccc34)cc2)cc1 ; CC(C)(C)c1ccc(-c2ccc(N3c4ccc(-c5ccc(C(C)(C)C)cc5)cc4B4c5c(cc6ccccc6c53)-c3cc(O)ccc3N4c3ccc(-c4ccccc4)cc3)cc2)cc1 ; O=S(=O)(F)C(F)(F)C(F)(F)C(F)(F)C(F)(F)F]

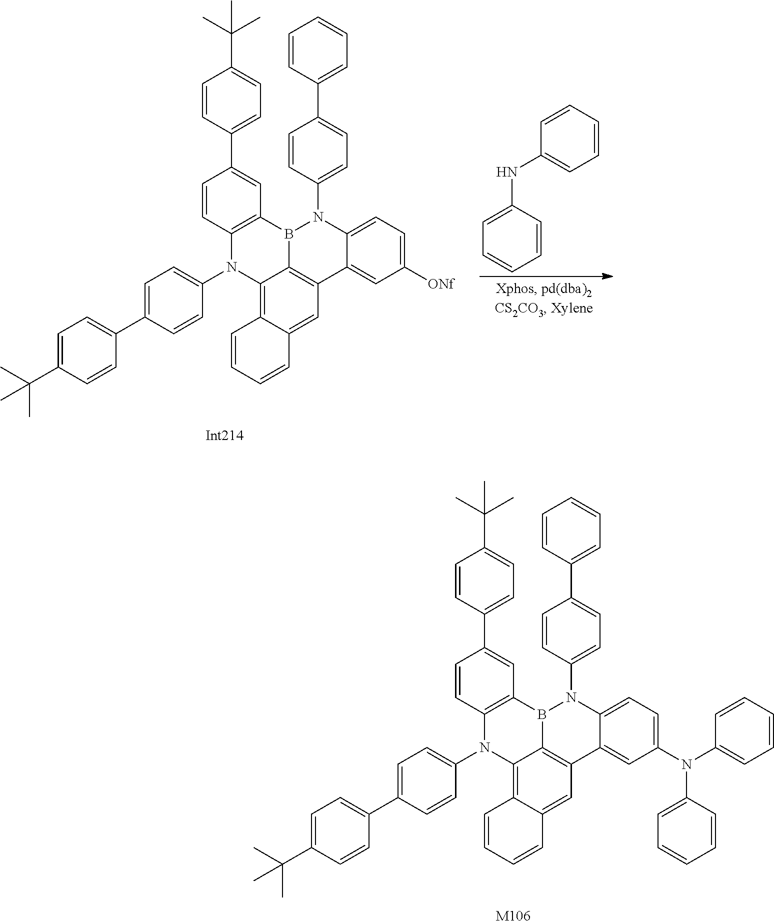

### 1) Synthesis of Int212

The same equivalents and method were used as in the synthesis process of Int135 using N,N-bis(4′-(tert-butyl)-[1,1′-biphenyl]-4-yl)-3-chloronaphthalen-1-amine and 4-([1,1′-biphenyl]-4-ylamino)-3-(4,4,5,5-tetramethyl-1,3,2-dioxaborolan-2-yl)phenol instead of Int134 and 3,6-di-tert-butyl-1-(4,4,5,5-tetramethyl-1,3,2-dioxaborolan-2-yl)-9H-carbazole, and after the reaction was finished, the result was extracted and then recrystallized to obtain Int212 (31 g, yield 75%). MS [M+H]+=820

### 2) Synthesis of Int213

Under the nitrogen atmosphere, Int212 (25 g) and boron triiodide (20.3 g) were introduced to 1,2-dichlorobenzene (250 ml), and stirred for 4 hours at 160° C. After the reaction was finished, the result was extracted, and then recrystallized to obtain Int213 (7.1 g, yield 28%). MS[M+H]+=828

3) Synthesis of Int214 Int213 (7 g), 1,1,2,2,3,3,4,4,4-nonafluorobutane-1-sulfonyl fluoride (2.3 ml) and potassium carbonate (3.5 g) were introduced to tetrahydrofuran (70 ml) and water (30 ml), and stirred for 2 hours under reflux. After the reaction was finished, the result was extracted, and then column purified to obtain Int214 (8.8 g, yield 94%). MS[M+H]+=1110

### 4) Synthesis of Compound M106

Under the nitrogen atmosphere, Int214 (7 g), diphenylamine (2.2 g), pd(dba)₂ (0.15 g), Xphos (0.24 g) and cesium carbonate (8.3 g) were introduced to xylene (100 ml), and stirred for 12 hours under reflux. After the reaction was finished, the result was extracted, and then recrystallized to obtain Compound M106 (4.5 g, yield 73%). MS [M+H]+=979

### Synthesis Example 107. Synthesis of Compound M107

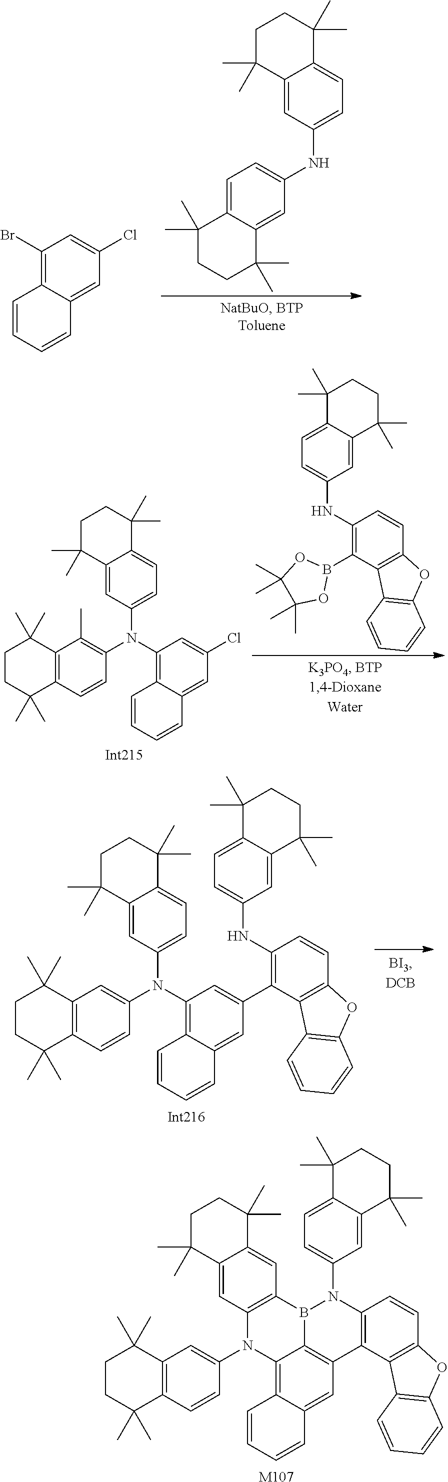

### 1) Synthesis of Int215

The same equivalents and method were used as in the synthesis process of Int134 using 1-bromo-3-chloronaphthalene and bis(5,5,8,8-tetramethyl-5,6,7,8-tetrahydronaphthalen-2-yl)amine instead of 2-bromo-4-chlorodibenzo[b,d]furan and di([1,1′-biphenyl]-4-yl)amine, and after the reaction was finished, the result was extracted and then recrystallized to obtain Int215 (49 g, yield 72%). MS[M+H]+=551

### 2) Synthesis of Int216

The same equivalents and method were used as in the synthesis process of Int135 using Int215 and 1-(4,4,5,5-tetramethyl-1,3,2-dioxaborolan-2-yl)-N-(5,5,8,8-tetramethyl-5,6,7,8-tetrahydronaphthalen-2-yl)dibenzo[b,d]furan-2-amine instead of Int134 and 3,6-di-tert-butyl-1-(4,4,5,5-tetramethyl-1,3,2-dioxaborolan-2-yl)-9H-carbazole, and after the reaction was finished, the result was extracted and then recrystallized to obtain Int216 (35.5 g, yield 74%). MS[M+H]+=884

### 3) Synthesis of Compound M107

Under the nitrogen atmosphere, Int216 (25 g) and boron triiodide (18.8 g) were introduced to 1,2-dichlorobenzene (250 ml), and stirred for 4 hours at 160° C. After the reaction was finished, the result was extracted, and then recrystallized to obtain Compound M107 (7.6 g, yield 30%). MS[M+H]+=892

### Synthesis Example 108. Synthesis of Compound M108

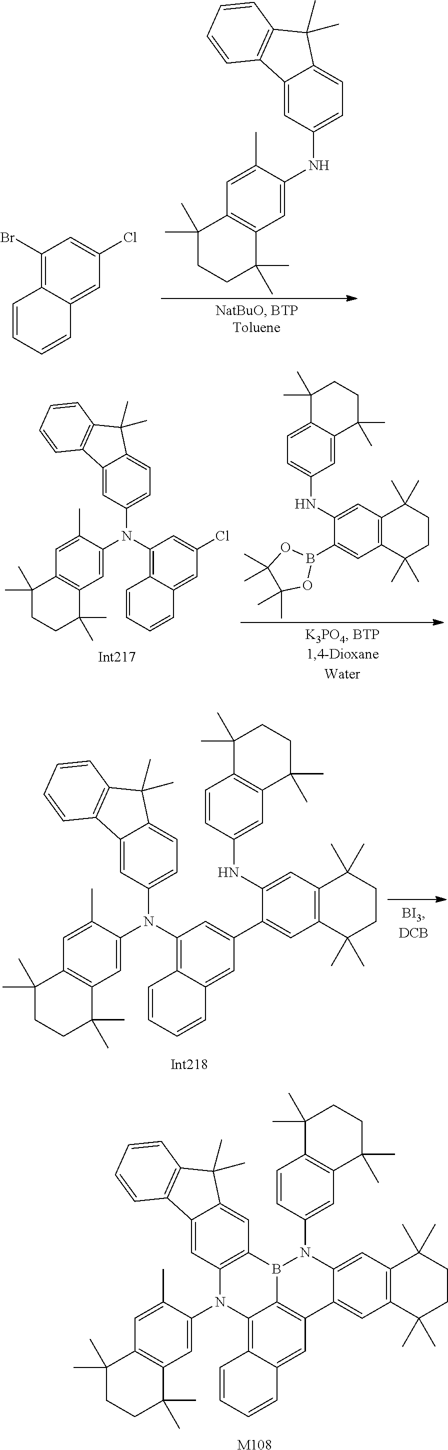

### 1) Synthesis of Int217

The same equivalents and method were used as in the synthesis process of Int134 using 1-bromo-3-chloronaphthalene and 9,9-dimethyl-N-(3,5,5,8,8-pentamethyl-5,6,7,8-tetrahydronaphthalen-2-yl)-9H-fluoren-3-amine instead of 2-bromo-4-chlorodibenzo[b, d]furan and di([1,1′-biphenyl]-4-yl)amine, and after the reaction was finished, the result was extracted and then recrystallized to obtain Int217 (53 g, yield 75%). MS[M+H]+=571

### 2) Synthesis of Int218

The same equivalents and method were used as in the synthesis process of Int135 using Int217 and 5,5,8,8-tetramethyl-3-(4,4,5,5-tetramethyl-1,3,2-dioxaborolan-2-yl)-N-(5,5,8,8-tetramethyl-5,6,7,8-tetrahydronaphthalen-2-yl)-5,6,7,8-tetrahydronaphthalen-2-amine instead of Int134 and 3,6-di-tert-butyl-1-(4,4,5,5-tetramethyl-1,3,2-dioxaborolan-2-yl)-9H-carbazole, and after the reaction was finished, the result was extracted and then recrystallized to obtain Int218 (34.8 g, yield 72%). MS[M+H]+=924

### 3) Synthesis of Compound M108

Under the nitrogen atmosphere, Int218 (25 g) and boron triiodide (18.1 g) were introduced to 1,2-dichlorobenzene (250 ml), and stirred for 4 hours at 160° C. After the reaction was finished, the result was extracted, and then recrystallized to obtain Compound M108 (7.4 g, yield 29%). MS[M+H]+=932

### Synthesis Example 109. Synthesis of Compound M109

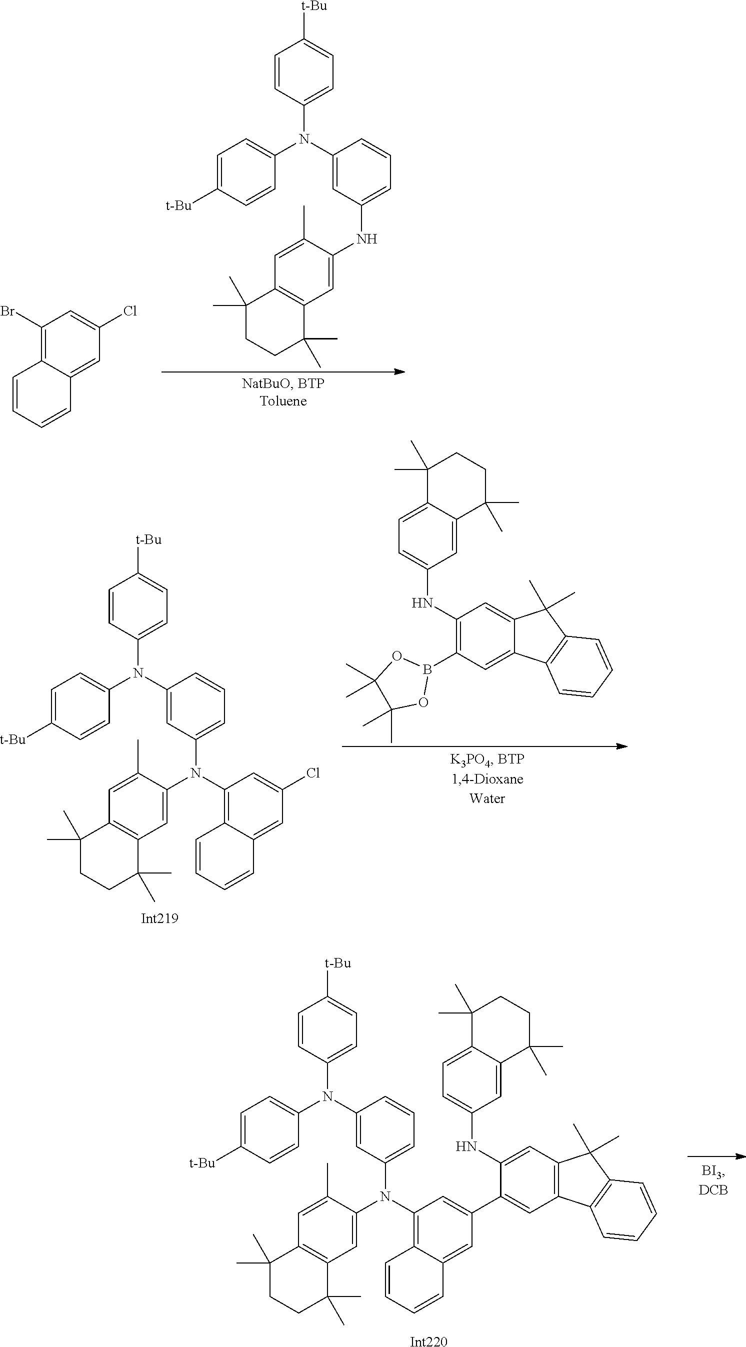

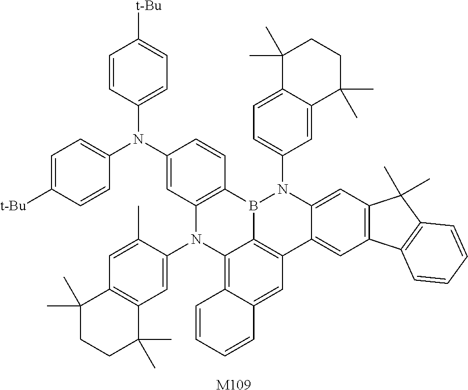

### 1) Synthesis of Int219

The same equivalents and method were used as in the synthesis process of Int134 using 1-bromo-3-chloronaphthalene and N1,N1-bis(4-(tert-butyl)phenyl)-N3-(3,5,5,8,8-pentamethyl-5,6,7,8-tetrahydronaphthalen-2-yl)benzene-1,3-diamine instead of 2-bromo-4-chlorodibenzo[b,d]furan and di([1,1′-biphenyl]-4-yl)amine, and after the reaction was finished, the result was extracted and then recrystallized to obtain Int219 (66 g, yield 72). MS[M+H]+=734

### 2) Synthesis of Int220

The same equivalents and method were used as in the synthesis process of Int135 using Int219 and 9,9-dimethyl-3-(4,4,5,5-tetramethyl-1,3,2-dioxaborolan-2-yl)-N-(5,5,8,8-tetramethyl-5,6,7,8-tetrahydronaphthalen-2-yl)-9H-fluoren-2-amine instead of Int134 and 3,6-di-tert-butyl-1-(4,4,5,5-tetramethyl-1,3,2-dioxaborolan-2-yl)-9H-carbazole, and after the reaction was finished, the result was extracted and then recrystallized to obtain Int220 (35.2 g, yield 79%). MS[M+H]+=1093

3) Synthesis of Compound M109 Under the nitrogen atmosphere, Int220 (25 g) and boron triiodide (15.3 g) were introduced to 1,2-dichlorobenzene (250 ml), and stirred for 4 hours at 160° C. After the reaction was finished, the result was extracted, and then recrystallized to obtain Compound M109 (7.5 g, yield 30%). MS[M+H]+=1101

### Synthesis Example 110. Synthesis of Compound M110

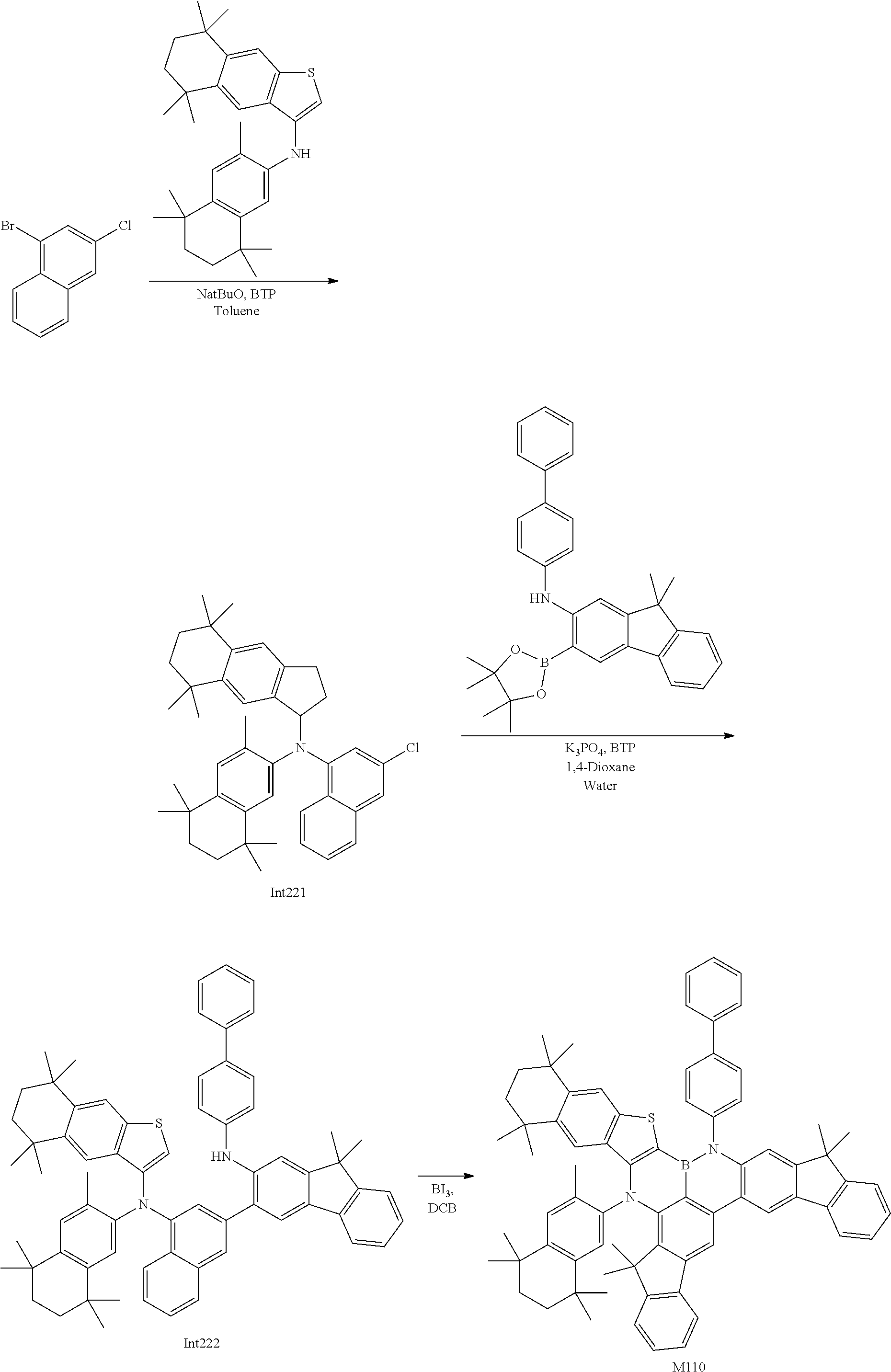

### 1) Synthesis of Int221

The same equivalents and method were used as in the synthesis process of Int134 using 1-bromo-3-chloronaphthalene and 5,5,8,8-tetramethyl-N-(3,5,5,8,8-pentamethyl-5,6,7,8-tetrahydronaphthalen-2-yl)-5,6,7,8-tetrahydronaphtho[2,3-b]thiophen-3-amine instead of 2-bromo-4-chlorodibenzo[b,d]furan and di([1,1′-biphenyl]-4-yl)amine, and after the reaction was finished, the result was extracted and then recrystallized to obtain Int221 (56.6 g, yield 73%). MS [M+H]+=621

### 2) Synthesis of Int222

The same equivalents and method were used as in the synthesis process of Int135 using Int221 and N-([1,1′-biphenyl]-4-yl)-9,9-dimethyl-3-(4,4,5,5-tetramethyl-1,3,2-dioxaborolan-2-yl)-9H-fluoren-2-amine instead of Int134 and 3,6-di-tert-butyl-1-(4,4,5,5-tetramethyl-1,3,2-dioxaborolan-2-yl)-9H-carbazole, and after the reaction was finished, the result was extracted and then recrystallized to obtain Int222 (34.8 g, yield 76%). MS[M+H]+=946

### 3) Synthesis of Compound M110

Under the nitrogen atmosphere, Int222 (25 g) and boron triiodide (17.6 g) were introduced to 1,2-dichlorobenzene (250 ml), and stirred for 4 hours at 160° C. After the reaction was finished, the result was extracted, and then recrystallized to obtain Compound M110 (7.2 g, yield 29%). MS[M+H]+=954

### Synthesis Example 111. Synthesis of Compound M111

### 1) Synthesis of Int223

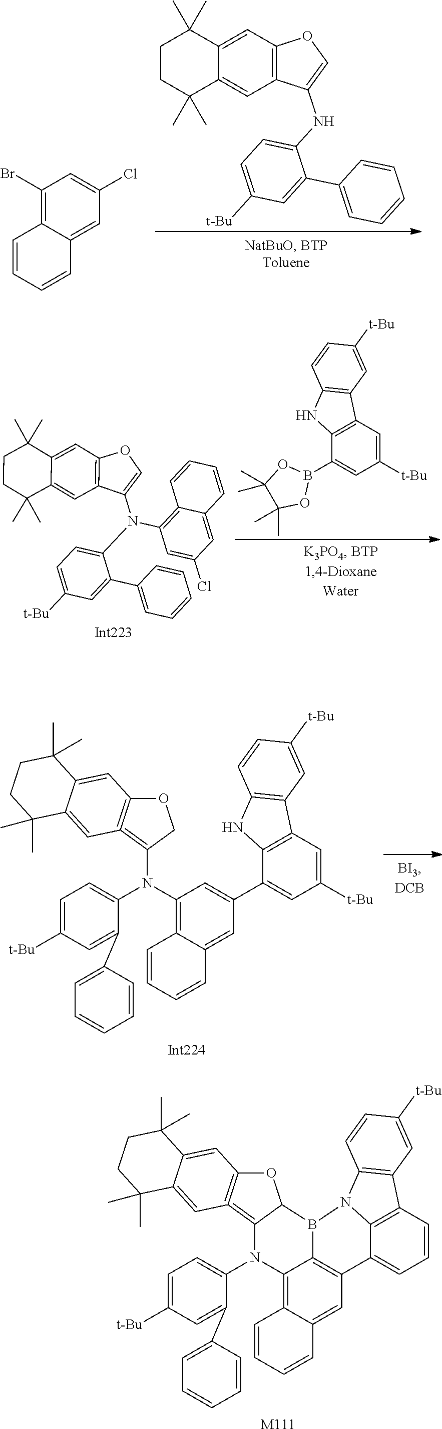

The same equivalents and method were used as in the synthesis process of Int134 using 1-bromo-3-chloronaphthalene and N-(5-(tert-butyl)-[1,1′-biphenyl]-2-yl)-5,5,8,8-tetramethyl-5,6,7,8-tetrahydronaphtho[2,3-b]furan-3-amine instead of 2-bromo-4-chlorodibenzo[b,d]furan and di([1,1′-biphenyl]-4-yl)amine, and after the reaction was finished, the result was extracted and then recrystallized to obtain Int223 (54.5 g, yield 72%). MS[M+H]+=613

### 2) Synthesis of Int224

The same equivalents and method were used as in the synthesis process of Int135 using Int223 instead of Int134, and after the reaction was finished, the result was extracted and then recrystallized to obtain Int224 (31.1 g, yield 74%). MS[M+H]+=856

### 3) Synthesis of Compound M111

Under the nitrogen atmosphere, Int224 (25 g) and boron triiodide (19.5 g) were introduced to 1,2-dichlorobenzene (250 ml), and stirred for 4 hours at 160° C. After the reaction was finished, the result was extracted, and then recrystallized to obtain Compound M111 (7.1 g, yield 28%). MS[M+H]+=864

### Synthesis Example 112. Synthesis of Compound M112

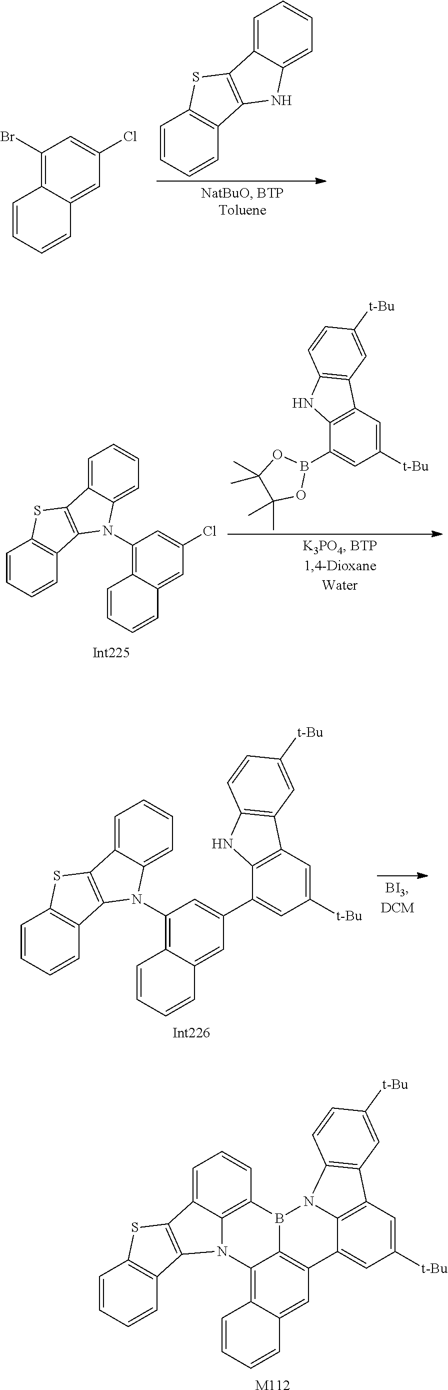

### 1) Synthesis of Int225

The same equivalents and method were used as in the synthesis process of Int134 using 1-bromo-3-chloronaphthalene and 10H-benzo[4,5]thieno[3,2-b]indole instead of 2-bromo-4-chlorodibenzo[b,d]furan and di([1,1′-biphenyl]-4-yl)amine, and after the reaction was finished, the result was extracted and then recrystallized to obtain Int225 (35 g, yield 73%). MS[M+H]+=385

### 2) Synthesis of Int226

The same equivalents and method were used as in the synthesis process of Int135 using Int225 instead of Int134, and after the reaction was finished, the result was extracted and then recrystallized to obtain Int226 (36.5 g, yield 75%). MS[M+H]+=628

### 3) Synthesis of Compound M112

Under the nitrogen atmosphere, Int226 (25 g) and boron triiodide (26.5 g) were introduced to 1,2-dichlorobenzene (250 ml), and stirred for 4 hours at 160° C. After the reaction was finished, the result was extracted, and then recrystallized to obtain Compound M112 (7.2 g, yield 28%). MS[M+H]+=636

### Synthesis Example 113. Synthesis of Compound M113

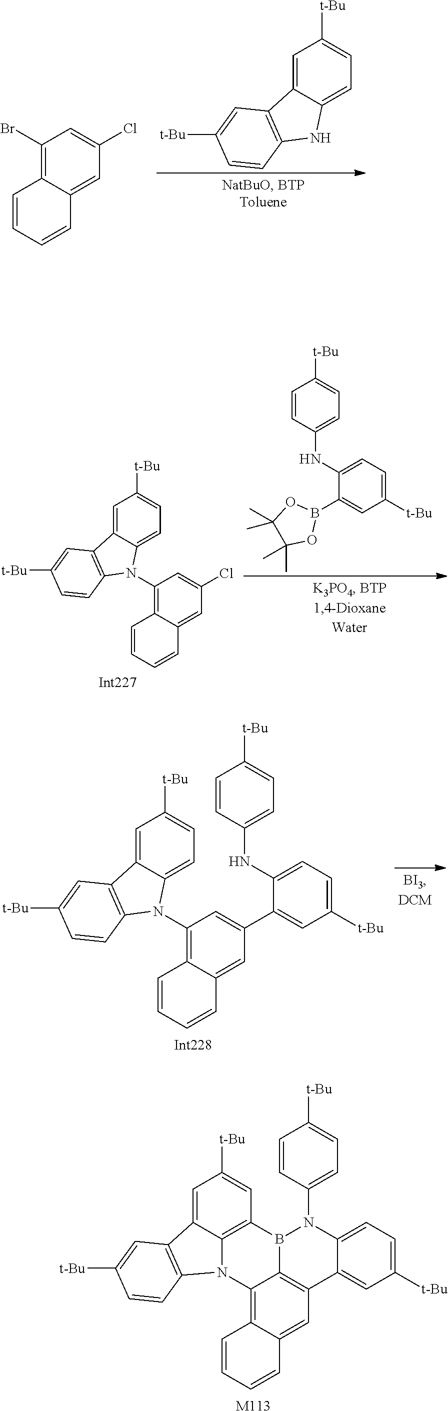

### 1) Synthesis of Int227

The same equivalents and method were used as in the synthesis process of Int134 using 1-bromo-3-chloronaphthalene and 3,6-di-tert-butyl-9H-carbazole instead of 2-bromo-4-chlorodibenzo[b, d]furan and di([1,1′-biphenyl]-4-yl)amine, and after the reaction was finished, the result was extracted and then recrystallized to obtain Int227 (39 g, yield 71%). MS [M+H]+=441

### 2) Synthesis of Int228

The same equivalents and method were used as in the synthesis process of Int135 using Int227 and 4-(tert-butyl)-N-(4-(tert-butyl) phenyl)-2-(4,4,5,5-tetramethyl-1,3,2-dioxaborolan-2-yl)aniline instead of Int134 and 3,6-di-tert-butyl-1-(4,4,5,5-tetramethyl-1,3,2-dioxaborolan-2-yl)-9H-carbazole, and after the reaction was finished, the result was extracted and then recrystallized to obtain Int228 (34.5 g, yield 74%). MS[M+H]+=686

### 3) Synthesis of Compound M113

Under the nitrogen atmosphere, Int228 (25 g) and boron triiodide (26.5 g) were introduced to 1,2-dichlorobenzene (250 ml), and stirred for 4 hours at 160° C. After the reaction was finished, the result was extracted, and then recrystallized to obtain Compound M113 (7.4 g, yield 29%). MS[M+H]+=694

### Synthesis Example 114. Synthesis of Compound M114

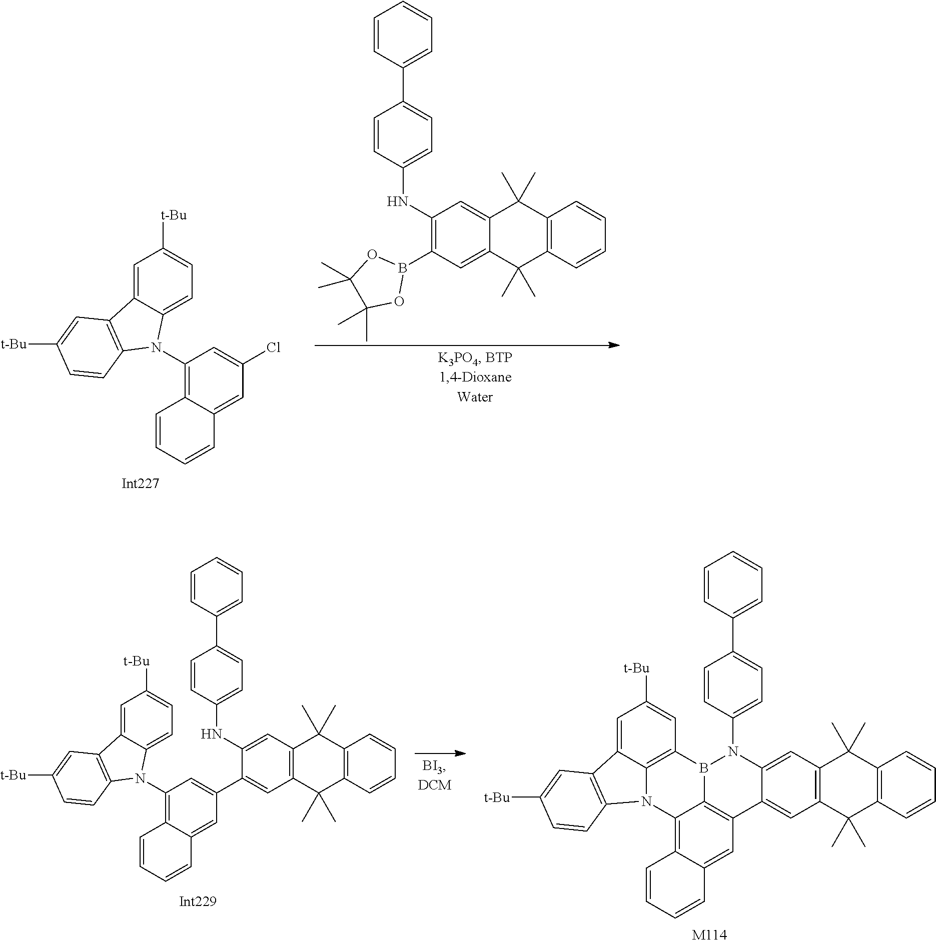

### 1) Synthesis of Int229

The same equivalents and method were used as in the synthesis process of Int135 using Int227 and N-([1,1′-biphenyl]-4-yl)-9,9,10,10-tetramethyl-3-(4,4,5,5-tetramethyl-1,3,2-dioxaborolan-2-yl)-9,10-dihydroanthracen-2-amine instead of Int134 and 3,6-di-tert-butyl-1-(4,4,5,5-tetramethyl-1,3,2-dioxaborolan-2-yl)-9H-carbazole, and after the reaction was finished, the result was extracted and then recrystallized to obtain Int229 (42.1 g, yield 77%). MS[M+H]+=808

### 2) Synthesis of Compound M114

Under the nitrogen atmosphere, Int229 (25 g) and boron triiodide (20.7 g) were introduced to 1,2-dichlorobenzene (250 ml), and stirred for 4 hours at 160° C. After the reaction was finished, the result was extracted, and then recrystallized to obtain Compound M114 (7.5 g, yield 30%). MS[M+H]+=816

### Synthesis Example 115. Synthesis of Compound M115

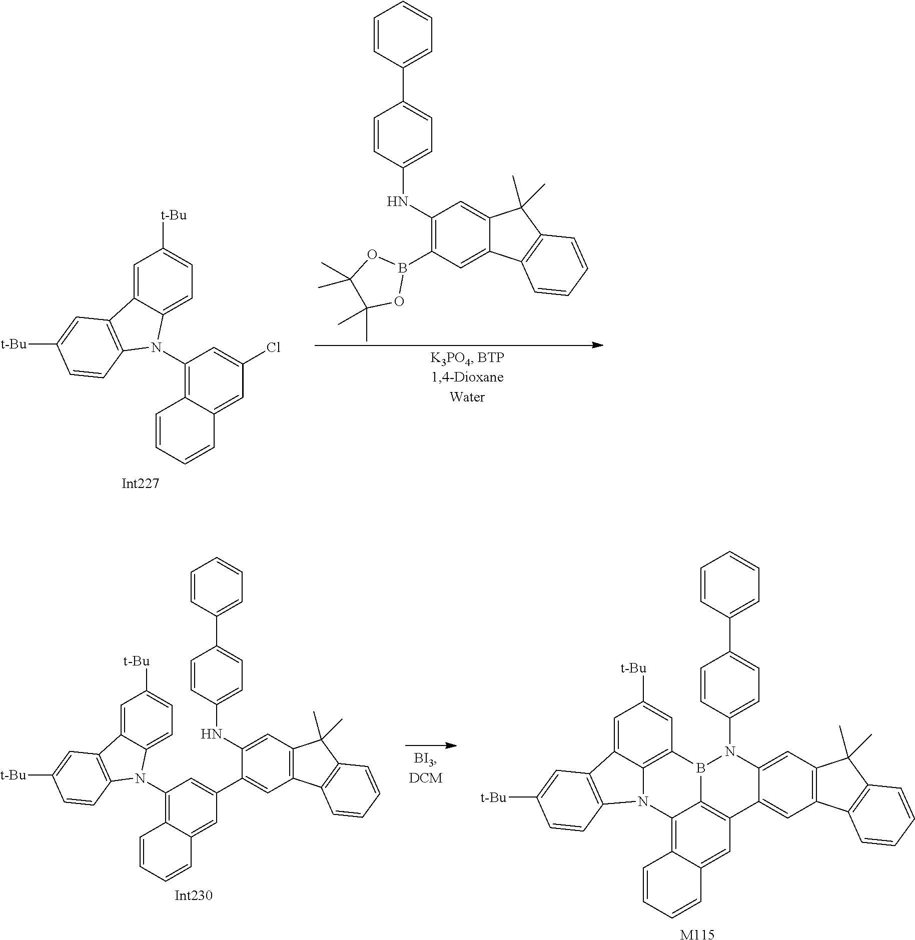

### 1) Synthesis of Int230

The same equivalents and method were used as in the synthesis process of Int135 using Int227 and N-([1,1′-biphenyl]-4-yl)-9,9-dimethyl-3-(4,4,5,5-tetramethyl-1,3,2-dioxaborolan-2-yl)-9H-fluoren-2-amine instead of Int134 and 3,6-di-tert-butyl-1-(4,4,5,5-tetramethyl-1,3,2-dioxaborolan-2-yl)-9H-carbazole, and after the reaction was finished, the result was extracted and then recrystallized to obtain Int230 (38.7 g, yield 74%). MS[M+H]+=766

### 2) Synthesis of Compound M115

Under the nitrogen atmosphere, Int230 (25 g) and boron triiodide (21.7 g) were introduced to 1,2-dichlorobenzene (250 ml), and stirred for 4 hours at 160° C. After the reaction was finished, the result was extracted, and then recrystallized to obtain Compound M115 (7.4 g, yield 29%). MS[M+H]+=774

### Synthesis Example 117. Synthesis of Compound M117

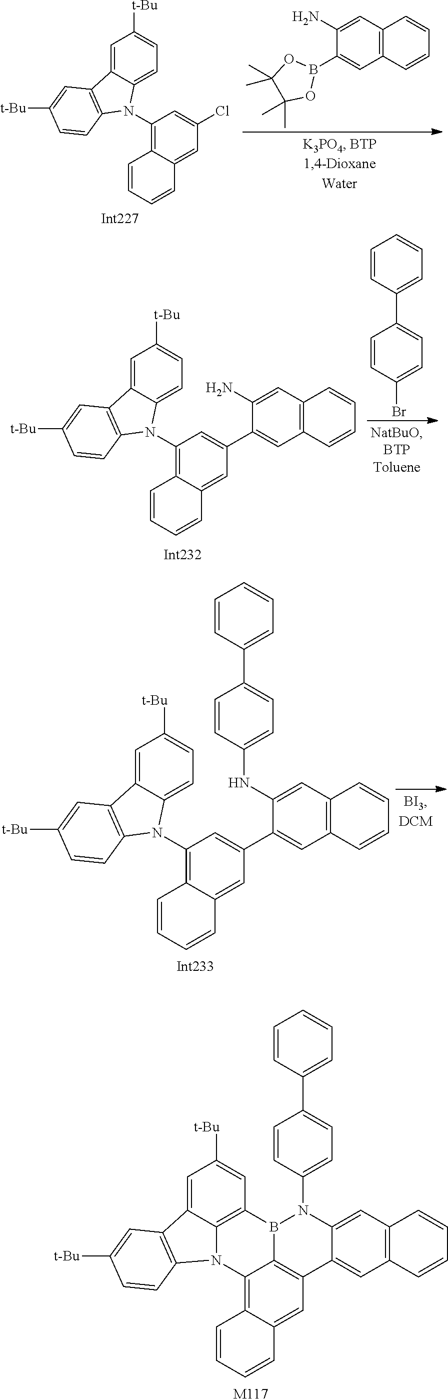

### 1) Synthesis of Int232

The same equivalents and method were used as in the synthesis process of Int135 using Int227 and 3-(4,4,5,5-tetramethyl-1,3,2-dioxaborolan-2-yl)naphthalen-2-amine instead of Int134 and 3,6-di-tert-butyl-1-(4,4,5,5-tetramethyl-1,3,2-dioxaborolan-2-yl)-9H-carbazole, and after the reaction was finished, the result was extracted and then recrystallized to obtain Int232 (27.8 g, yield 75%). MS[M+H]+=548

### 2) Synthesis of Int233

The same equivalents and method were used as in the synthesis process of Int134 using Int232 (27 g) and 4-bromo-1,1′-biphenyl (11.5 g) instead of 2-bromo-4-chlorodibenzo[b,d]furan and di([1,1′-biphenyl]-4-yl)amine, and after the reaction was finished, the result was extracted and then recrystallized to obtain Int233 (26.4 g, yield 76%). MS [M+H]+=700

### 3) Synthesis of Compound M117

Under the nitrogen atmosphere, Int233 (25 g) and boron triiodide (23.8 g) were introduced to 1,2-dichlorobenzene (250 ml), and stirred for 4 hours at 160° C. After the reaction was finished, the result was extracted, and then recrystallized to obtain Compound M117 (7.4 g, yield 29%). MS[M+H]+=708

### Synthesis Example 118. Synthesis of Compound M118

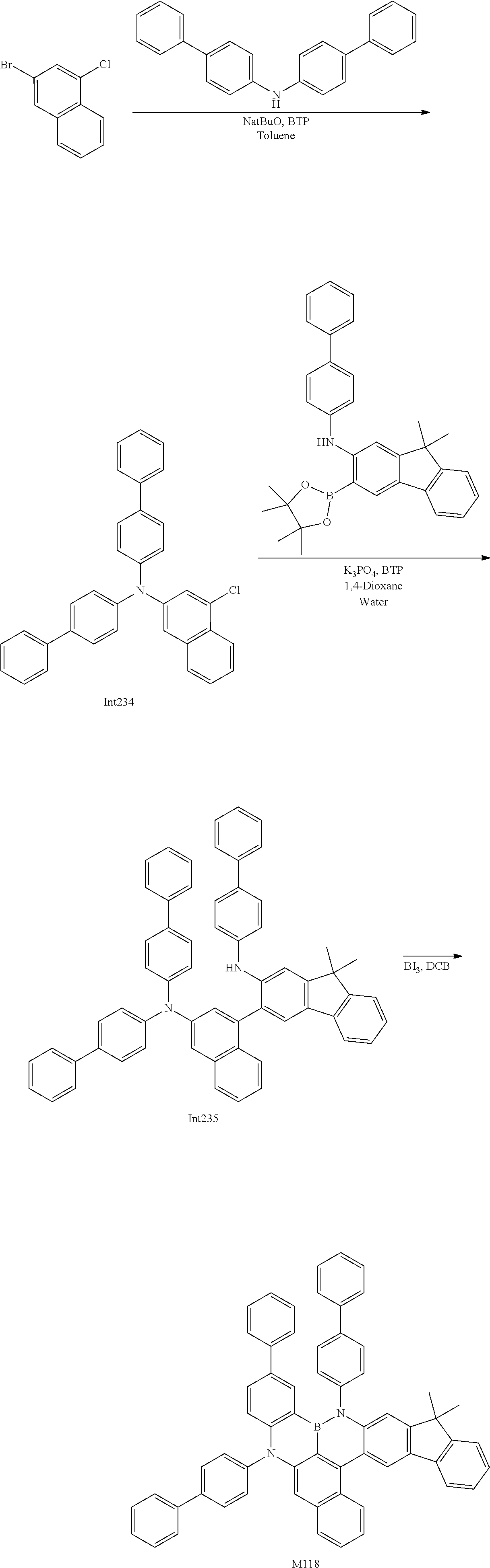

### 1) Synthesis of Int234

The same equivalents and method were used as in the synthesis process of Int134 using 1-bromo-3-chloronaphthalene instead of 2-bromo-4-chlorodibenzo[b,d]furan, and after the reaction was finished, the result was extracted and then recrystallized to obtain Int234 (43 g, yield 72%). MS[M+H]+=483

### 2) Synthesis of Int235

The same equivalents and method were used as in the synthesis process of Int135 using Int234 and N-([1,1′-biphenyl]-4-yl)-9,9-dimethyl-3-(4,4,5,5-tetramethyl-1,3,2-dioxaborolan-2-yl)-9H-fluoren-2-amine instead of Int134 and 3,6-di-tert-butyl-1-(4,4,5,5-tetramethyl-1,3,2-dioxaborolan-2-yl)-9H-carbazole, and after the reaction was finished, the result was extracted and then recrystallized to obtain Int235 (38 g, yield 76%). MS[M+H]+=808

### 3) Synthesis of Compound M118

Under the nitrogen atmosphere, Int235 (25 g) and boron triiodide (20.6 g) were introduced to 1,2-dichlorobenzene (250 ml), and stirred for 4 hours at 160° C. After the reaction was finished, the result was extracted, and then recrystallized to obtain Compound M118 (7.5 g, yield 30%). MS[M+H]+=816

### Synthesis Example 119. Synthesis of Compound M119

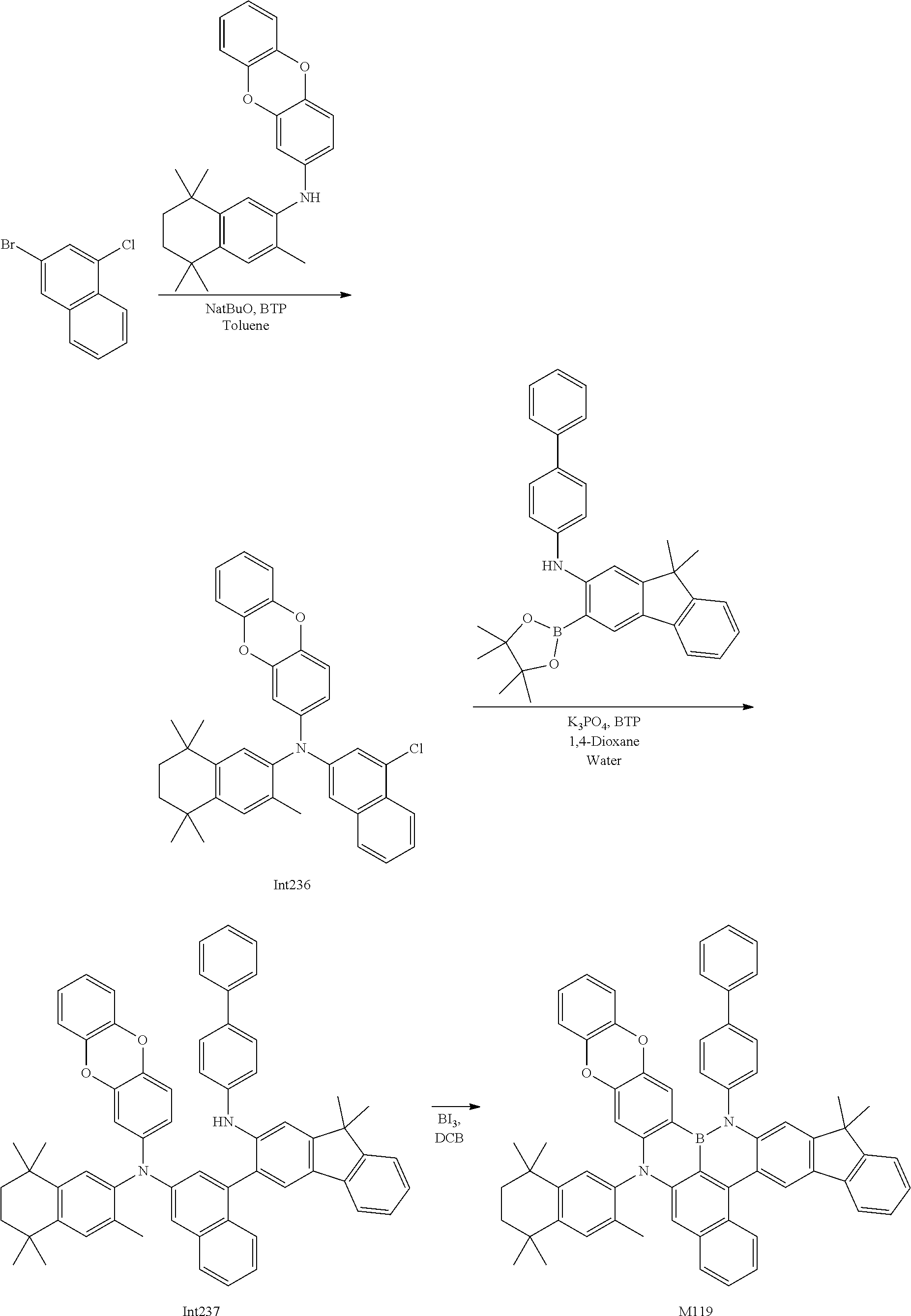

### 1) Synthesis of Int236

The same equivalents and method were used as in the synthesis process of Int134 using 1-bromo-3-chloronaphthalene and N-(3,5,5,8,8-pentamethyl-5,6,7,8-tetrahydronaphthalen-2-yl)dibenzo[b,e][1,4]dioxin-2-amine instead of 2-bromo-4-chlorodibenzo[b,d]furan and di([1,1′-biphenyl]-4-yl)amine, and after the reaction was finished, the result was extracted and then recrystallized to obtain Int236 (49.3 g, yield 71%). MS[M+H]+=561

### 2) Synthesis of Int237

The same equivalents and method were used as in the synthesis process of Int135 using Int236 and N-([1,1′-biphenyl]-4-yl)-9,9-dimethyl-3-(4,4,5,5-tetramethyl-1,3,2-dioxaborolan-2-yl)-9H-fluoren-2-amine instead of Int134 and 3,6-di-tert-butyl-1-(4,4,5,5-tetramethyl-1,3,2-dioxaborolan-2-yl)-9H-carbazole, and after the reaction was finished, the result was extracted and then recrystallized to obtain Int237 (36.6 g, yield 77%). MS[M+H]+=886

### 3) Synthesis of Compound M119

Under the nitrogen atmosphere, Int237 (25 g) and boron triiodide (18.8 g) were introduced to 1,2-dichlorobenzene (250 ml), and stirred for 4 hours at 160° C. After the reaction was finished, the result was extracted, and then recrystallized to obtain Compound M119 (7.4 g, yield 29%). MS[M+H]+=894

### Synthesis Example 120. Synthesis of Compound M120

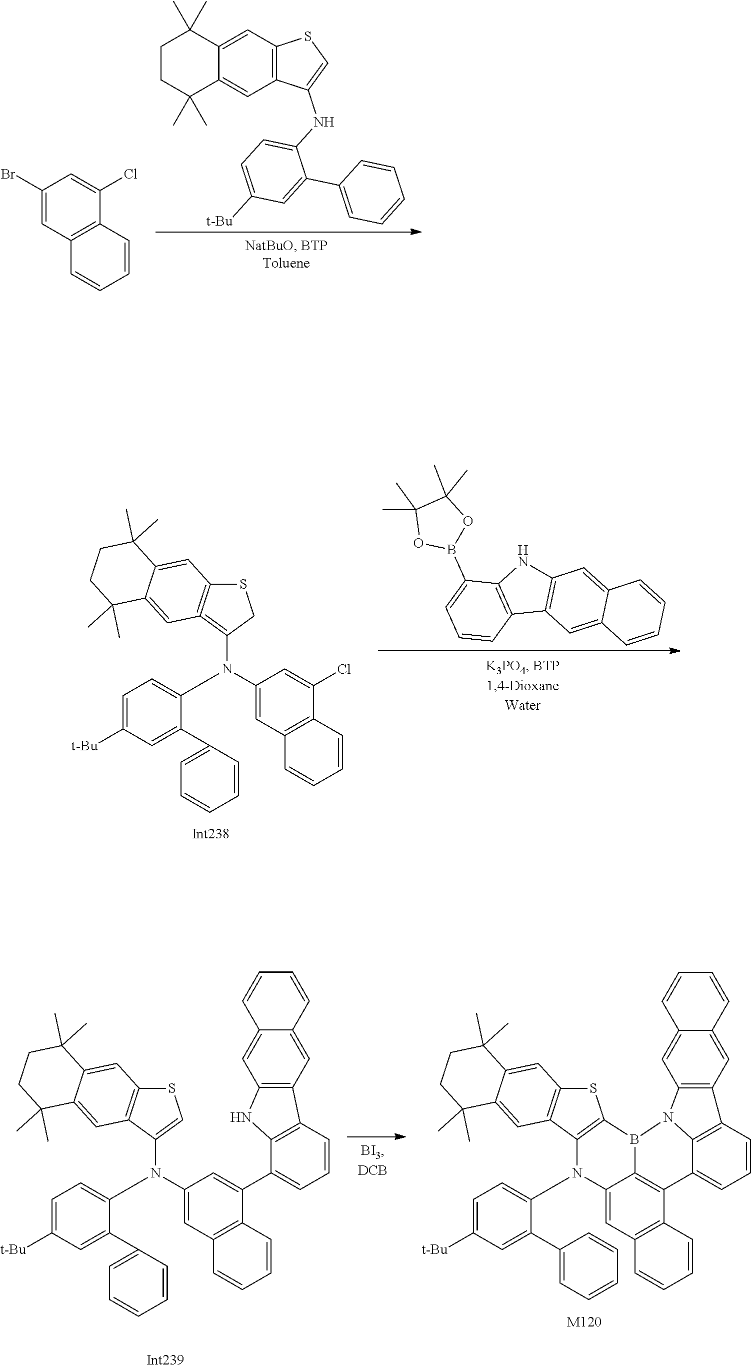

### 1) Synthesis of Int238

The same equivalents and method were used as in the synthesis process of Int134 using 1-bromo-3-chloronaphthalene and N-(5-(tert-butyl)-[1,1′-biphenyl]-2-yl)-5,5,8,8-tetramethyl-5,6,7,8-tetrahydronaphtho[2,3-b]thiophen-3-amine instead of 2-bromo-4-chlorodibenzo[b,d]furan and di([1,1′-biphenyl]-4-yl)amine, and after the reaction was finished, the result was extracted and then recrystallized to obtain Int238 (56.6 g, yield 73%). MS[M+H]+=629

### 2) Synthesis of Int239

The same equivalents and method were used as in the synthesis process of Int135 using Int238 and 4-(4,4,5,5-tetramethyl-1,3,2-dioxaborolan-2-yl)-5H-benzo[b]carbazole instead of Int134 and 3,6-di-tert-butyl-1-(4,4,5,5-tetramethyl-1,3,2-dioxaborolan-2-yl)-9H-carbazole, and after the reaction was finished, the result was extracted and then recrystallized to obtain Int239 (28.3 g, yield 73%). MS[M+H]+=810

### 3) Synthesis of Compound M120

Under the nitrogen atmosphere, Int239 (25 g) and boron triiodide (20.6 g) were introduced to 1,2-dichlorobenzene (250 ml), and stirred for 4 hours at 160° C. After the reaction was finished, the result was extracted, and then recrystallized to obtain Compound M120 (7.5 g, yield 30%). MS[M+H]+=818

### Synthesis Example 121. Synthesis of Compound M121

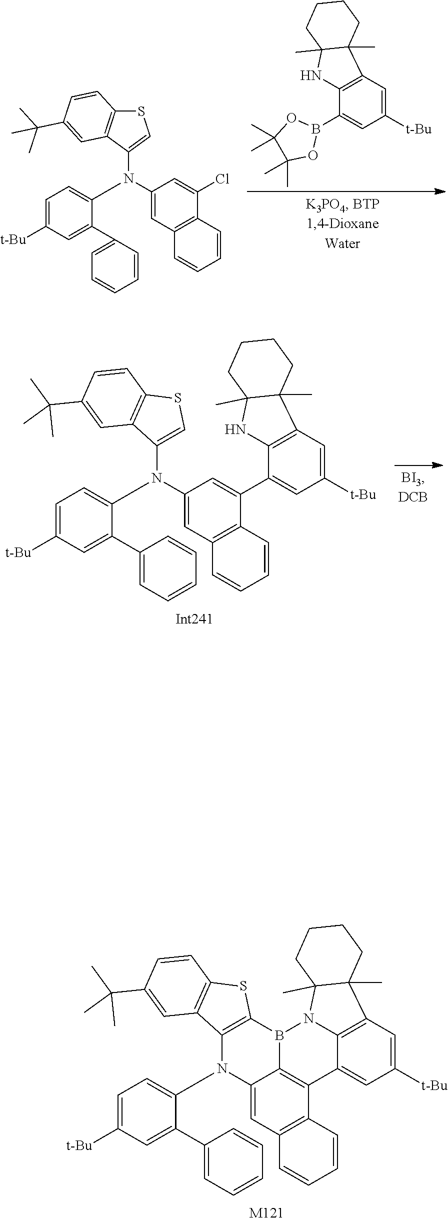

### 1) Synthesis of Int241

The same equivalents and method were used as in the synthesis process of Int135 using 5-(tert-butyl)-N-(5-(tert-butyl)-[1,1′-biphenyl]-2-yl)-N-(4-chloronaphthalen-2-yl)benzo[b]thiophen-3-amine and 6-(tert-butyl)-4a,9a-dimethyl-8-(4,4,5,5-tetramethyl-1,3,2-dioxaborolan-2-yl)-2,3,4,4a,9,9a-hexahydro-1H-carbazole instead of Int134 and 3,6-di-tert-butyl-1-(4,4,5,5-tetramethyl-1,3,2-dioxaborolan-2-yl)-9H-carbazole, and after the reaction was finished, the result was extracted and then recrystallized to obtain Int241 (30.2 g, yield 73%). MS[M+H]+=796

### 2) Synthesis of Compound M121

Under the nitrogen atmosphere, Int241 (25 g) and boron triiodide (20.9 g) were introduced to 1,2-dichlorobenzene (250 ml), and stirred for 4 hours at 160° C. After the reaction was finished, the result was extracted, and then recrystallized to obtain Compound M121 (7.3 g, yield 29%). MS[M+H]+=804

### Synthesis Example 122. Synthesis of Compound M122

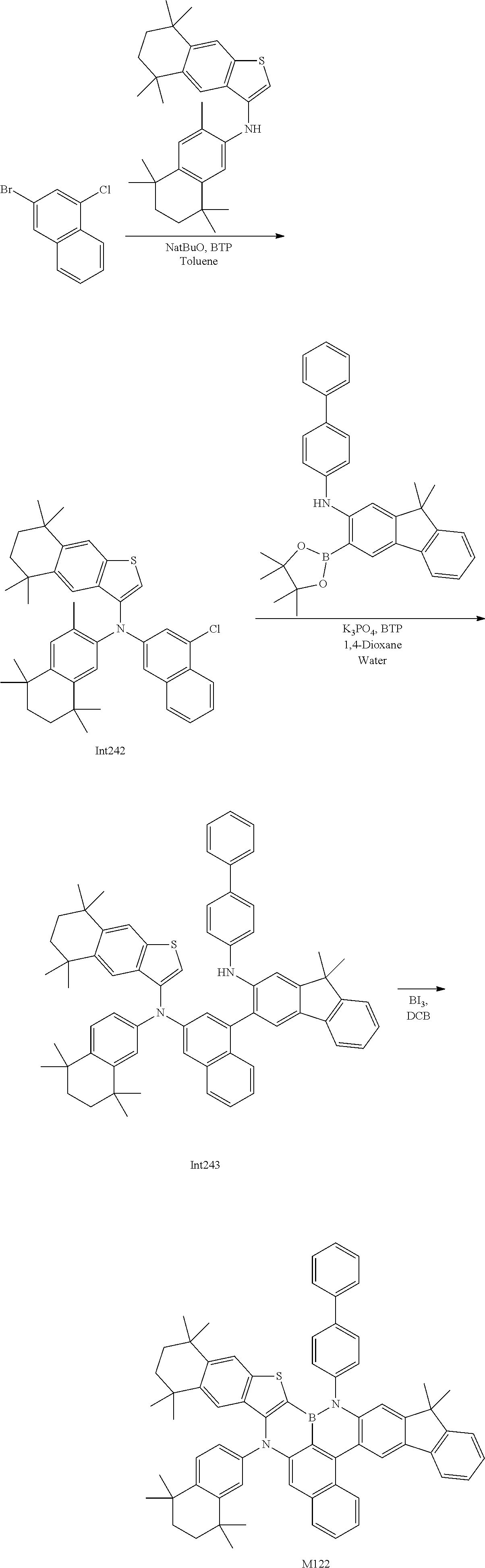

### 1) Synthesis of Int242

The same equivalents and method were used as in the synthesis process of Int134 using 1-bromo-3-chloronaphthalene and 5,5,8,8-tetramethyl-N-(3,5,5,8,8-pentamethyl-5,6,7,8-tetrahydronaphthalen-2-yl)-5,6,7,8-tetrahydronaphtho[2,3-b]thiophen-3-amine instead of 2-bromo-4-chlorodibenzo[b,d]furan and di([1,1′-biphenyl]-4-yl)amine, and after the reaction was finished, the result was extracted and then recrystallized to obtain Int242 (55.5 g, yield 72%). MS [M+H]+=621

### 2) Synthesis of Int243

The same equivalents and method were used as in the synthesis process of Int135 using Int242 and N-([1,1′-biphenyl]-4-yl)-9,9-dimethyl-3-(4,4,5,5-tetramethyl-1,3,2-dioxaborolan-2-yl)-9H-fluoren-2-amine instead of Int134 and 3,6-di-tert-butyl-1-(4,4,5,5-tetramethyl-1,3,2-dioxaborolan-2-yl)-9H-carbazole, and after the reaction was finished, the result was extracted and then recrystallized to obtain Int243 (32.4 g, yield 71%). MS[M+H]+=946

### 3) Synthesis of Compound M122

Under the nitrogen atmosphere, Int243 (25 g) and boron triiodide (17.6 g) were introduced to 1,2-dichlorobenzene (250 ml), and stirred for 4 hours at 160° C. After the reaction was finished, the result was extracted, and then recrystallized to obtain Compound M122 (7.3 g, yield 29%). MS[M+H]+=954

### Synthesis Example 123. Synthesis of Compound M123

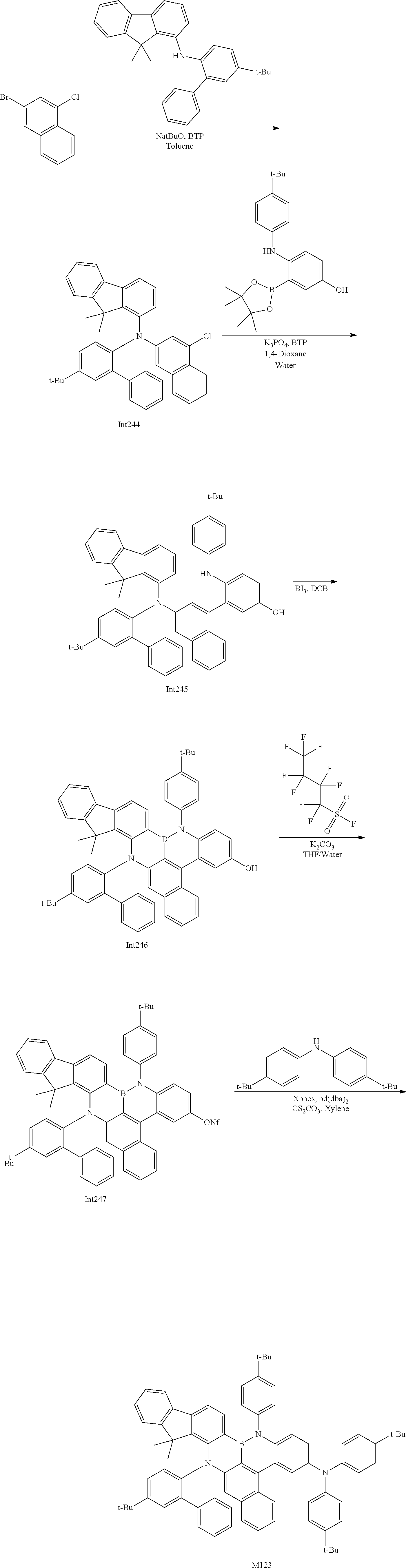

### 1) Synthesis of Int244

The same equivalents and method were used as in the synthesis process of Int134 using 1-bromo-3-chloronaphthalene and N-(5-(tert-butyl)-[1,1′-biphenyl]-2-yl)-9,9-dimethyl-9H-fluoren-1-amine instead of 2-bromo-4-chlorodibenzo[b,d]furan and di([1,1′-biphenyl]-4-yl)amine, and after the reaction was finished, the result was extracted and then recrystallized to obtain Int244 (54.5 g, yield 76%). MS[M+H]+=579

### 2) Synthesis of Int245

The same equivalents and method were used as in the synthesis process of Int135 using Int244 and 4-((4-(tert-butyl)phenyl)amino)-3-(4,4,5,5-tetramethyl-1,3,2-dioxaborolan-2-yl)phenol instead of Int134 and 3,6-di-tert-butyl-1-(4,4,5,5-tetramethyl-1,3,2-dioxaborolan-2-yl)-9H-carbazole, and after the reaction was finished, the result was extracted and then recrystallized to obtain Int245 (31 g, yield 76%). MS[M+H]+=784

### 3) Synthesis of Int246

Under the nitrogen atmosphere, Int245 (25 g) and boron triiodide (21.2 g) were introduced to 1,2-dichlorobenzene (250 ml), and stirred for 4 hours at 160° C. After the reaction was finished, the result was extracted, and then recrystallized to obtain Int246 (7.2 g, yield 29%). MS[M+H]+=792

### 4) Synthesis of Int247

Int246 (7 g), 1,1,2,2,3,3,4,4,4-nonafluorobutane-1-sulfonyl fluoride (2.4 ml) and potassium carbonate (3.7 g) were introduced to tetrahydrofuran (70 ml) and water (30 ml), and stirred for 2 hours under reflux. After the reaction was finished, the result was extracted, and then column purified to obtain Int247 (8.8 g, yield 93%). MS[M+H]+=1074

### 5) Synthesis of Compound M123

Under the nitrogen atmosphere, Int247 (7 g), bis(4-(tert-butyl)phenyl)amine (1.1 g), pd(dba)₂ (0.11 g), Xphos (0.19 g) and cesium carbonate (6.4 g) were introduced to xylene (100 ml), and stirred for 12 hours under reflux. After the reaction was finished, the result was extracted, and then recrystallized to obtain Compound M123 (4.9 g, yield 71%). MS[M+H]+=1055

### Synthesis Example 124. Synthesis of Compound M124

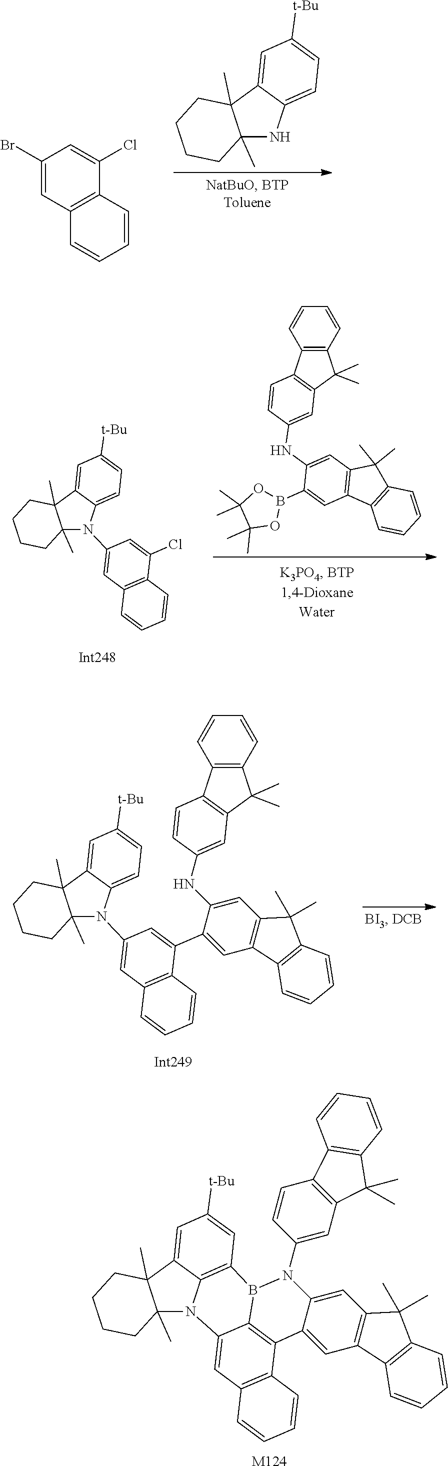

### 1) Synthesis of Int248

The same equivalents and method were used as in the synthesis process of Int134 using 3-bromo-1-chloronaphthalene and 6-(tert-butyl)-4a,9a-dimethyl-2,3,4,4a,9,9a-hexahydro-1H-carbazole instead of 2-bromo-4-chlorodibenzo[b,d]furan and di([1,1′-biphenyl]-4-yl)amine, and after the reaction was finished, the result was extracted and then recrystallized to obtain Int248 (38.7 g, yield 75%). MS[M+H]+=419

### 2) Synthesis of Int249

The same equivalents and method were used as in the synthesis process of Int135 using Int248 and N-(9,9-dimethyl-9H-fluoren-2-yl)-9,9-dimethyl-3-(4,4,5,5-tetramethyl-1,3,2-dioxaborolan-2-yl)-9H-fluoren-2-amine instead of Int134 and 3,6-di-tert-butyl-1-(4,4,5,5-tetramethyl-1,3,2-dioxaborolan-2-yl)-9H-carbazole, and after the reaction was finished, the result was extracted and then recrystallized to obtain Int249 (43.2 g, yield 77%). MS[M+H]+=784

### 3) Synthesis of Compound M124

Under the nitrogen atmosphere, Int249 (25 g) and boron triiodide (21.3 g) were introduced to 1,2-dichlorobenzene (250 ml), and stirred for 4 hours at 160° C. After the reaction was finished, the result was extracted, and then recrystallized to obtain Compound M124 (7.3 g, yield 29%). MS[M+H]+=792

### Synthesis Example 125. Synthesis of Compound M125

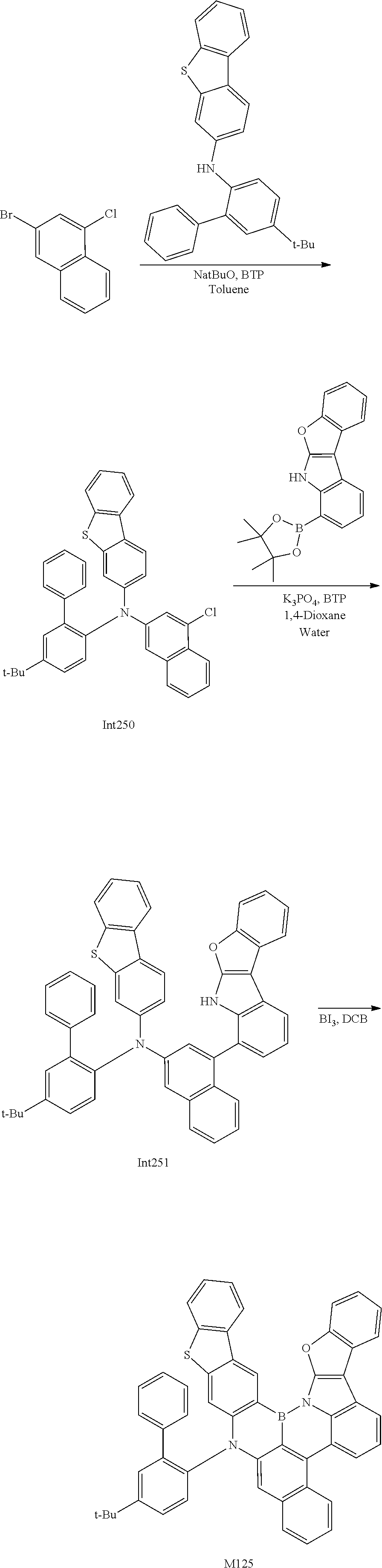

### 1) Synthesis of Int250

The same equivalents and method were used as in the synthesis process of Int134 using 3-bromo-1-chloronaphthalene and N-(5-(tert-butyl)-[1,1′-biphenyl]-2-yl)dibenzo[b,d]thiophen-3-amine instead of 2-bromo-4-chlorodibenzo[b,d]furan and di([1,1′-biphenyl]-4-yl)amine, and after the reaction was finished, the result was extracted and then recrystallized to obtain Int250 (51.4 g, yield 73%). MS[M+H]+=569

### 2) Synthesis of Int251

The same equivalents and method were used as in the synthesis process of Int135 using Int250 and 7-(4,4,5,5-tetramethyl-1,3,2-dioxaborolan-2-yl)-6H-benzofuro[2,3-b]indole instead of Int134 and 3,6-di-tert-butyl-1-(4,4,5,5-tetramethyl-1,3,2-dioxaborolan-2-yl)-9H-carbazole, and after the reaction was finished, the result was extracted and then recrystallized to obtain Int251 (29.8 g, yield 76%). MS[M+H]+=740

### 3) Synthesis of Compound M125

Under the nitrogen atmosphere, Int251 (25 g) and boron triiodide (22.5 g) were introduced to 1,2-dichlorobenzene (250 ml), and stirred for 4 hours at 160° C. After the reaction was finished, the result was extracted, and then recrystallized to obtain Compound M125 (7.1 g, yield 28%). MS[M+H]+=748

### Synthesis Example 126. Synthesis of Compound M126

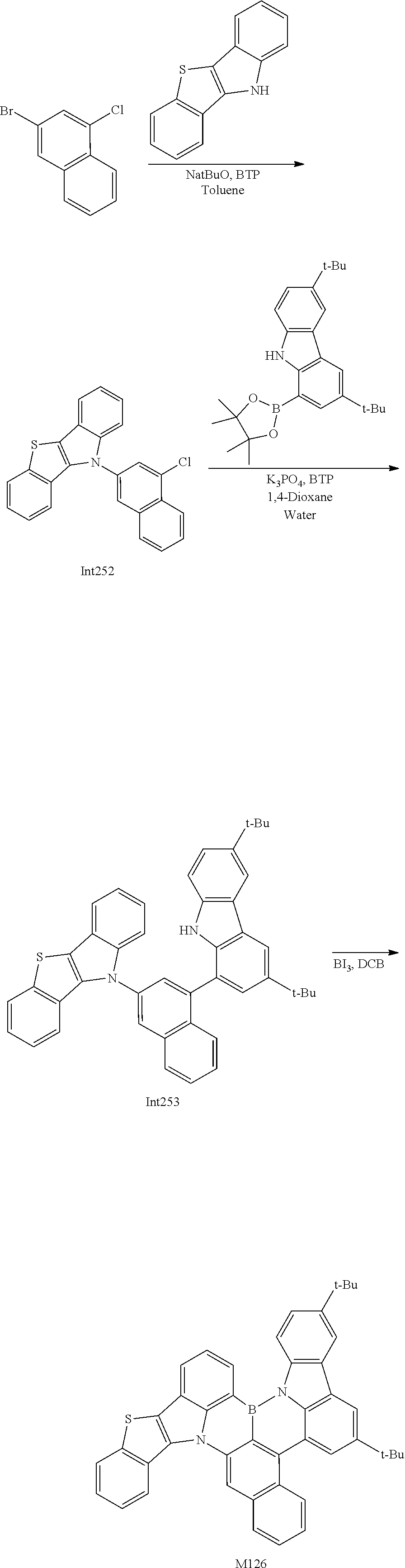

### 1) Synthesis of Int252

The same equivalents and method were used as in the synthesis process of Int134 using 3-bromo-1-chloronaphthalene and 10H-benzo[4,5]thieno[3,2-b]indole instead of 2-bromo-4-chlorodibenzo[b,d]furan and di([1,1′-biphenyl]-4-yl)amine, and after the reaction was finished, the result was extracted and then recrystallized to obtain Int252 (36 g, yield 76%). MS[M+H]+=384

### 2) Synthesis of Int253

The same equivalents and method were used as in the synthesis process of Int135 using Int252 instead of Int134, and after the reaction was finished, the result was extracted and then recrystallized to obtain Int253 (36.7 g, yield 75%). MS[M+H]+=628

### 3) Synthesis of Compound M126

Under the nitrogen atmosphere, Int253 (25 g) and boron triiodide (26.5 g) were introduced to 1,2-dichlorobenzene (250 ml), and stirred for 4 hours at 160° C. After the reaction was finished, the result was extracted, and then recrystallized to obtain Compound M126 (7.4 g, yield 29%). MS[M+H]+=636

### Synthesis Example 127. Synthesis of Compound M127

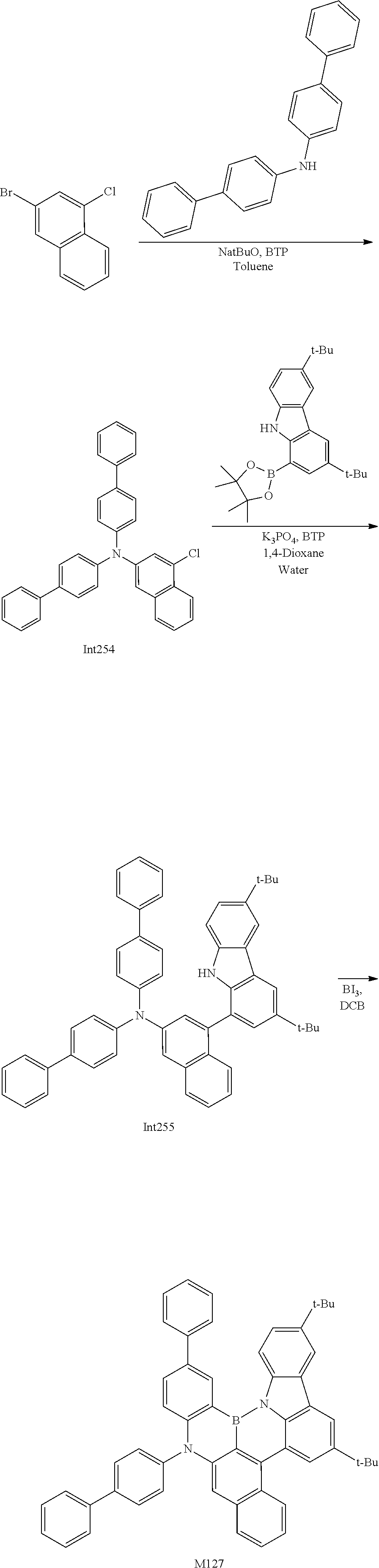

### 1) Synthesis of Int254

The same equivalents and method were used as in the synthesis process of Int134 using 3-bromo-1-chloronaphthalene instead of 2-bromo-4-chlorodibenzo[b,d]furan, and after the reaction was finished, the result was extracted and then recrystallized to obtain Int254 (43.1 g, yield 72%). MS[M+H]+=483

### 2) Synthesis of Int255

The same equivalents and method were used as in the synthesis process of Int135 using Int254 instead of Int134, and after the reaction was finished, the result was extracted and then recrystallized to obtain Int255 (35.5 g, yield 79%). MS[M+H]+=726

### 3) Synthesis of Compound M127

Under the nitrogen atmosphere, Int255 (25 g) and boron triiodide (22.4 g) were introduced to 1,2-dichlorobenzene (250 ml), and stirred for 4 hours at 160° C. After the reaction was finished, the result was extracted, and then recrystallized to obtain Compound M127 (7.2 g, yield 29%). MS[M+H]+=734

### Synthesis Example 128. Synthesis of Compound M128

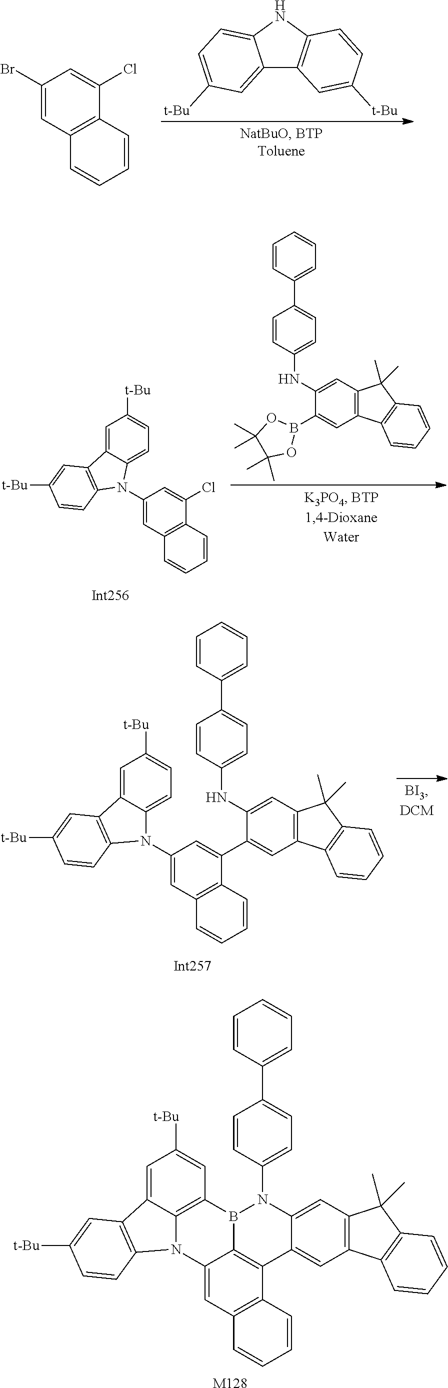

### 1) Synthesis of Int256

The same equivalents and method were used as in the synthesis process of Int134 using 3-bromo-1-chloronaphthalene and 3,6-di-tert-butyl-9H-carbazole instead of 2-bromo-4-chlorodibenzo[b,d]furan and di([1,1′-biphenyl]-4-yl)amine, and after the reaction was finished, the result was extracted and then recrystallized to obtain Int256 (42.8 g, yield 78%). MS[M+H]+=441

### 2) Synthesis of Int257

The same equivalents and method were used as in the synthesis process of Int135 using Int256 and N-([1,1′-biphenyl]-4-yl)-9,9-dimethyl-3-(4,4,5,5-tetramethyl-1,3,2-dioxaborolan-2-yl)-9H-fluoren-2-amine instead of Int134 and 3,6-di-tert-butyl-1-(4,4,5,5-tetramethyl-1,3,2-dioxaborolan-2-yl)-9H-carbazole, and after the reaction was finished, the result was extracted and then recrystallized to obtain Int257 (38.8 g, yield 74%). MS[M+H]+=766

### 3) Synthesis of Compound M128

Under the nitrogen atmosphere, Int257 (25 g) and boron triiodide (21.7 g) were introduced to 1,2-dichlorobenzene (250 ml), and stirred for 4 hours at 160° C. After the reaction was finished, the result was extracted, and then recrystallized to obtain Compound M128 (7.4 g, yield 29%). MS[M+H]+=774

### Synthesis Example 130. Synthesis of Compound M130

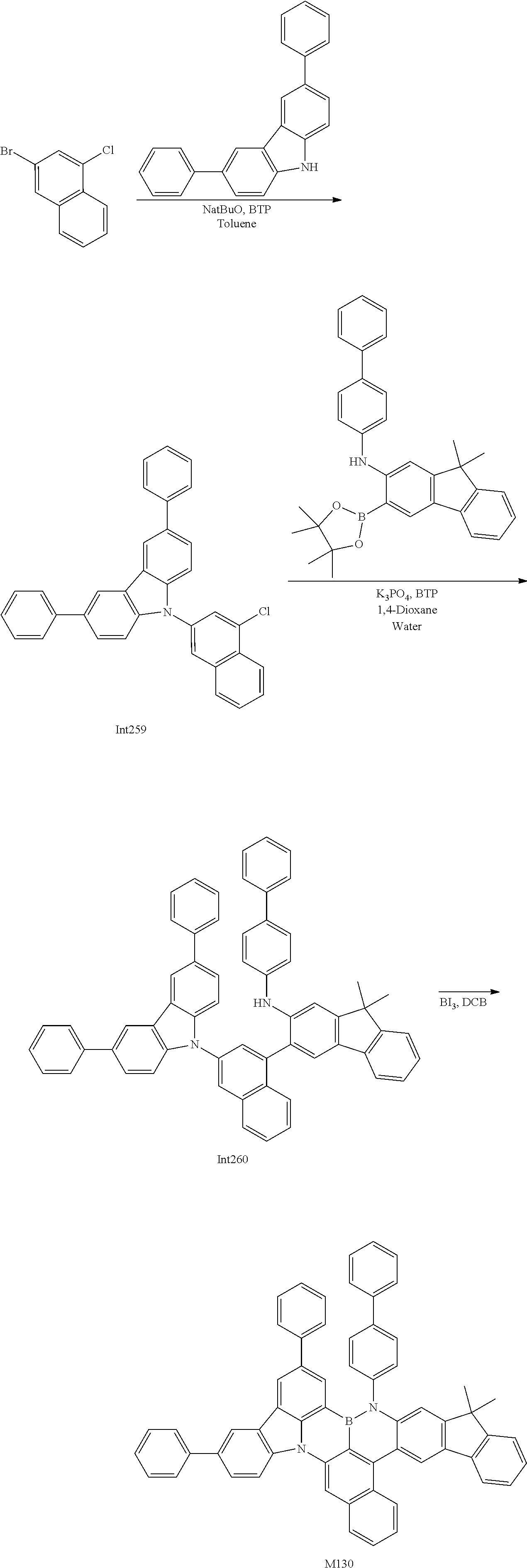

### 1) Synthesis of Int259

The same equivalents and method were used as in the synthesis process of Int134 using 3-bromo-1-chloronaphthalene and 3,6-diphenyl-9H-carbazole instead of 2-bromo-4-chlorodibenzo[b,d]furan and di([1,1′-biphenyl]-4-yl)amine, and after the reaction was finished, the result was extracted and then recrystallized to obtain Int259 (43.1 g, yield 72%). MS[M+H]+=481

### 2) Synthesis of Int260

The same equivalents and method were used as in the synthesis process of Int135 using Int259 and N-([1,1′-biphenyl]-4-yl)-9,9-dimethyl-3-(4,4,5,5-tetramethyl-1,3,2-dioxaborolan-2-yl)-9H-fluoren-2-amine instead of Int134 and 3,6-di-tert-butyl-1-(4,4,5,5-tetramethyl-1,3,2-dioxaborolan-2-yl)-9H-carbazole, and after the reaction was finished, the result was extracted and then recrystallized to obtain Int260 (38.2 g, yield 76%). MS[M+H]+=806

### 3) Synthesis of Compound M130

Under the nitrogen atmosphere, Int260 (25 g) and boron triiodide (20.7 g) were introduced to 1,2-dichlorobenzene (250 ml), and stirred for 4 hours at 160° C. After the reaction was finished, the result was extracted, and then recrystallized to obtain Compound M130 (7.2 g, yield 29%). MS[M+H]+=814

### Synthesis Example 131. Synthesis of Compound M131

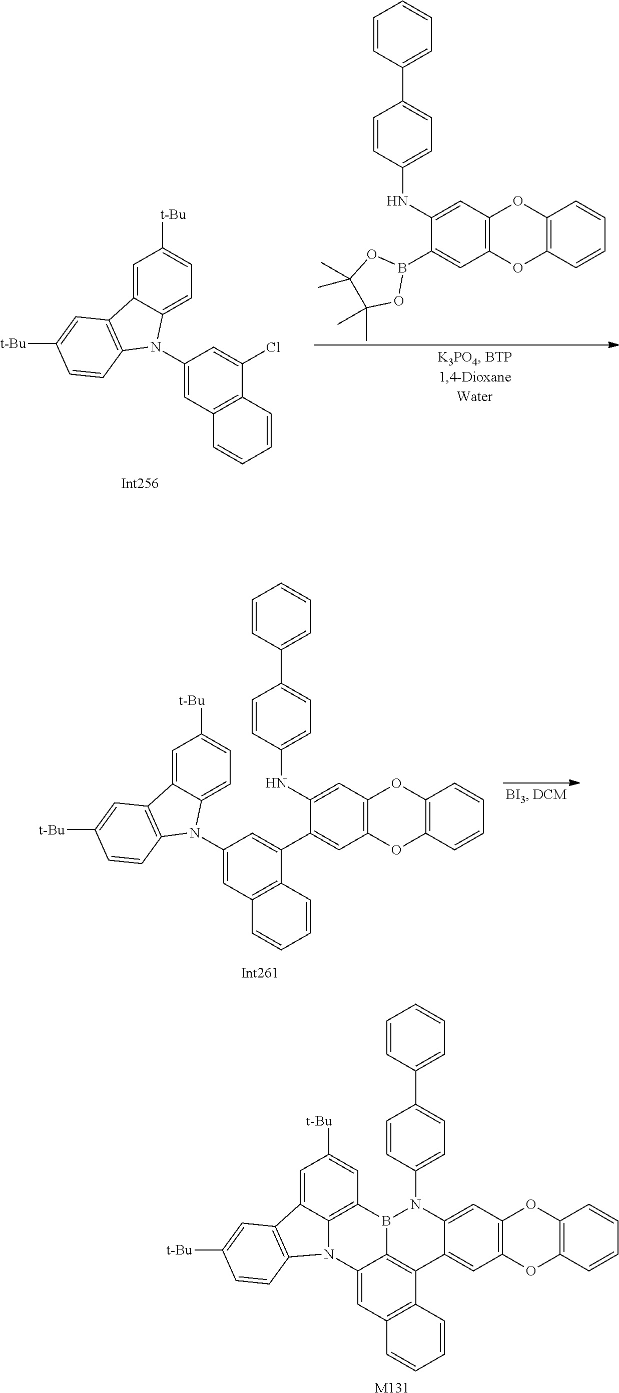

### 1) Synthesis of Int261

The same equivalents and method were used as in the synthesis process of Int135 using Int256 and N-([1,1′-biphenyl]-4-yl)-3-(4,4,5,5-tetramethyl-1,3,2-dioxaborolan-2-yl)dibenzo[b,e][1,4]dioxin-2-amine instead of Int134 and 3,6-di-tert-butyl-1-(4,4,5,5-tetramethyl-1,3,2-dioxaborolan-2-yl)-9H-carbazole, and after the reaction was finished, the result was extracted and then recrystallized to obtain Int261 (35.6 g, yield 75%). MS[M+H]+=756

### 2) Synthesis of Compound M131

Under the nitrogen atmosphere, Int261 (25 g) and boron triiodide (22.1 g) were introduced to 1,2-dichlorobenzene (250 ml), and stirred for 4 hours at 160° C. After the reaction was finished, the result was extracted, and then recrystallized to obtain Compound M131 (7.3 g, yield 29%). MS[M+H]+=764

### Synthesis Example 133. Synthesis of Compound M133

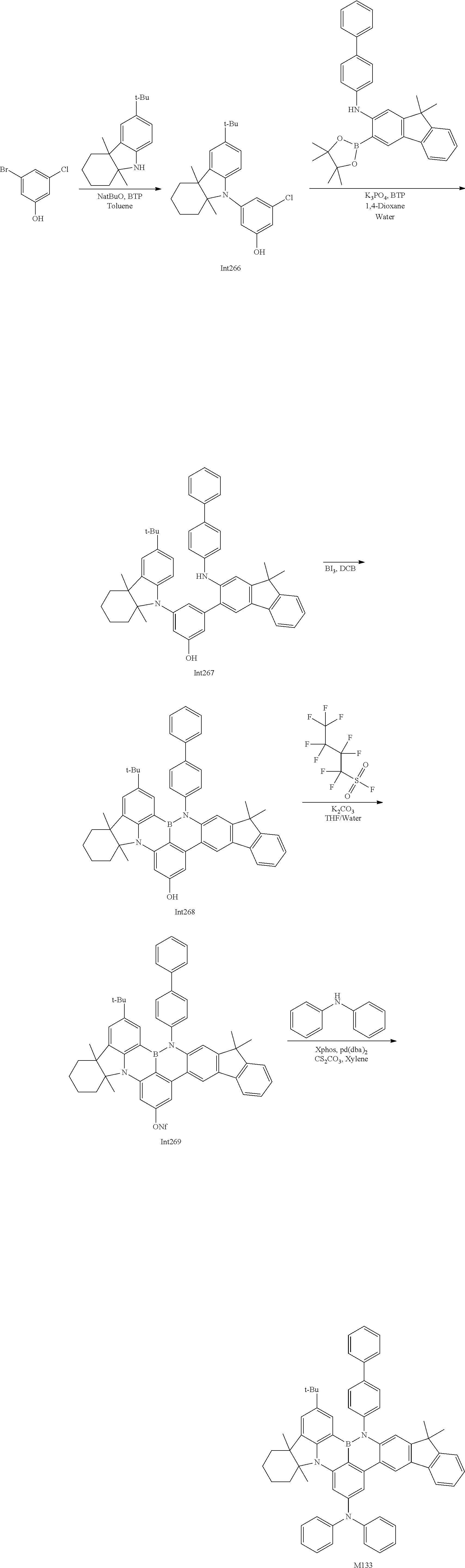

### 1) Synthesis of Int266

3-Bromo-5-chlorophenol (30 g), 6-(tert-butyl)-4a, 9a-dimethyl-2,3,4,4a,9,9a-hexahydro-1H-carbazole (37.2 g), sodium-tert-butoxide (42 g) and bis(tri-tert-butylphosphine)palladium(0) (1.5 g) were introduced to toluene (600 ml), and refluxed for 1 hour. After the reaction was finished, the result was extracted and then recrystallized to obtain Int266 (41.1 g, yield 74%). MS[M+H]+=385

### 2) Synthesis of Int267

Int266 (30 g), N-([1,1′-biphenyl]-4-yl)-9,9-dimethyl-3-(4,4,5,5-tetramethyl-1,3,2-dioxaborolan-2-yl)-9H-fluoren-2-amine (31.7 g), tripotassium phosphate (49.8 g) and bis(tri-tert-butylphosphine)palladium(0) (0.8 g) were introduced to 1,4-dioxane (300 ml) and water (100 ml), and refluxed for 2 hours. After the reaction was finished, the result was extracted and then recrystallized to obtain Int267 (39.2 g, yield 71%). MS[M+H]+=710

### 3) Synthesis of Int268

Under the nitrogen atmosphere, Int267 (25 g) and boron triiodide (22 g) were introduced to 1,2-dichlorobenzene (250 ml), and stirred for 4 hours at 160° C. After the reaction was finished, the result was extracted, and then recrystallized to obtain Int268 (7.2 g, yield 30%). MS[M+H]+=718

### 4) Synthesis of Int269

Int268 (7 g), 1,1,2,2,3,3,4,4,4-nonafluorobutane-1-sulfonyl fluoride (2.6 ml) and potassium carbonate (4.1 g) were introduced to tetrahydrofuran (70 ml) and water (30 ml), and stirred for 2 hours under reflux. After the reaction was finished, the result was extracted, and then column purified to obtain Int269 (9.1 g, yield 93%). MS[M+H]+=1000

### 5) Synthesis of Compound M133

Under the nitrogen atmosphere, Int269 (7 g), diphenylamine (1.2 g), pd(dba)₂ (0.12 g), Xphos (0.20 g) and cesium carbonate (6.9 g) were introduced to xylene (100 ml), and stirred for 12 hours under reflux. After the reaction was finished, the result was extracted, and then recrystallized to obtain Compound M133 (4.7 g, yield 77%). MS [M+H]+=869

### Synthesis Example 134. Synthesis of Compound M134

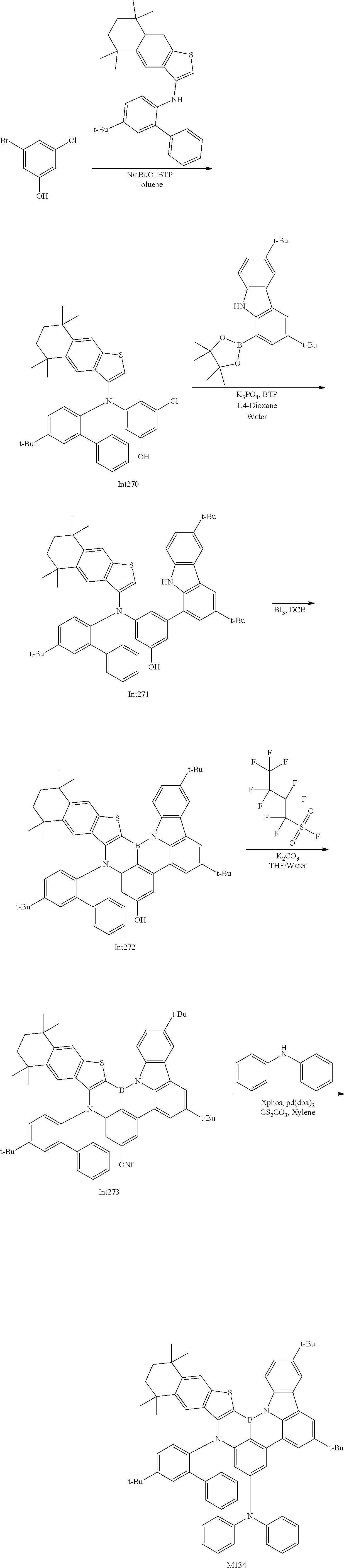

### 1) Synthesis of Int270

The same equivalents and method were used as in the synthesis process of Int266 using N-(5-(tert-butyl)-[1,1′-biphenyl]-2-yl)-5,5,8,8-tetramethyl-5,6,7,8-tetrahydronaphtho[2,3-b]thiophen-3-amine instead of 6-(tert-butyl)-4a,9a-dimethyl-2,3,4,4a,9,9a-hexahydro-1H-carbazole, and the result was recrystallized to obtain Int270 (62 g, yield 72%). MS[M+H]+=595

### 2) Synthesis of Int271

The same equivalents and method were used as in the synthesis process of Int267 using Int270 and 3,6-di-tert-butyl-1-(4,4,5,5-tetramethyl-1,3,2-dioxaborolan-2-yl)-9H-carbazole instead of Int266 and N-([1,1′-biphenyl]-4-yl)-9,9-dimethyl-3-(4,4,5,5-tetramethyl-1,3,2-dioxaborolan-2-yl)-9H-fluoren-2-amine, and the result was recrystallized to obtain Int271 (33.2 g, yield 79%). MS[M+H]+=838

### 3) Synthesis of Int272

Under the nitrogen atmosphere, Int271 (25 g) and boron triiodide (19.9 g) were introduced to 1,2-dichlorobenzene (250 ml), and stirred for 4 hours at 160° C. After the reaction was finished, the result was extracted, and then recrystallized to obtain Int272 (7.1 g, yield 28%). MS[M+H]+=846

### 4) Synthesis of Int273

Int272 (7 g), 1,1,2,2,3,3,4,4,4-nonafluorobutane-1-sulfonyl fluoride (2.3 ml) and potassium carbonate (3.4 g) were introduced to tetrahydrofuran (70 ml) and water (30 ml), and stirred for 2 hours under reflux. After the reaction was finished, the result was extracted, and then column purified to obtain Int273 (8.6 g, yield 92%). MS[M+H]+=1128

### 5) Synthesis of Compound M134

Under the nitrogen atmosphere, Int273 (7 g), diphenylamine (1.1 g), pd(dba)₂ (0.11 g), Xphos (0.18 g) and cesium carbonate (6.1 g) were introduced to xylene (100 ml), and stirred for 12 hours under reflux. After the reaction was finished, the result was extracted, and then recrystallized to obtain Compound M134 (4.8 g, yield 78%). MS [M+H]+=997

### Synthesis Example 135. Synthesis of Compound M135

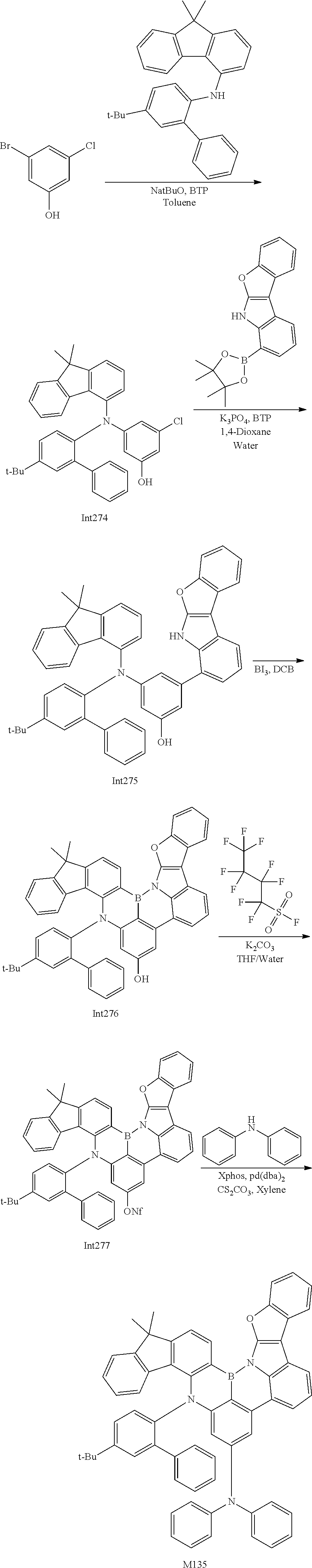

### 1) Synthesis of Int274

The same equivalents and method were used as in the synthesis process of Int266 using N-(5-(tert-butyl)-[1,1′-biphenyl]-2-yl)-9,9-dimethyl-9H-fluoren-4-amine instead of 6-(tert-butyl)-4a,9a-dimethyl-2,3,4,4a,9,9a-hexahydro-1H-carbazole, and the result was recrystallized to obtain Int274 (58 g, yield 74%). MS [M+H]+=545

### 2) Synthesis of Int275

The same equivalents and method were used as in the synthesis process of Int267 using Int274 and 7-(4,4,5,5-tetramethyl-1,3,2-dioxaborolan-2-yl)-6H-benzofuro[2,3-b]indole instead of Int266 and N-([1,1′-biphenyl]-4-yl)-9,9-dimethyl-3-(4,4,5,5-tetramethyl-1,3,2-dioxaborolan-2-yl)-9H-fluoren-2-amine, and the result was recrystallized to obtain Int275 (29.2 g, yield 74%). MS[M+H]+=716

### 3) Synthesis of Int276

Under the nitrogen atmosphere, Int275 (25 g) and boron triiodide (23.3 g) were introduced to 1,2-dichlorobenzene (250 ml), and stirred for 4 hours at 160° C. After the reaction was finished, the result was extracted, and then recrystallized to obtain Int276 (7.2 g, yield 28%). MS[M+H]+=724

### 4) Synthesis of Int277

Int276 (7 g), 1,1,2,2,3,3,4,4,4-nonafluorobutane-1-sulfonyl fluoride (2.6 ml) and potassium carbonate (4.1 g) were introduced to tetrahydrofuran (70 ml) and water (30 ml), and stirred for 2 hours under reflux. After the reaction was finished, the result was extracted, and then column purified to obtain Int277 (9.2 g, yield 95%). MS[M+H]+=1006

### 5) Synthesis of Compound M135

Under the nitrogen atmosphere, Int277 (7 g), diphenylamine (1.2 g), pd(dba)₂ (0.12 g), Xphos (0.20 g) and cesium carbonate (6.1 g) were introduced to xylene (100 ml), and stirred for 12 hours under reflux. After the reaction was finished, the result was extracted, and then recrystallized to obtain Compound M135 (4.4 g, yield 72%). MS [M+H]+=875

### Synthesis Example 136. Synthesis of Compound M136

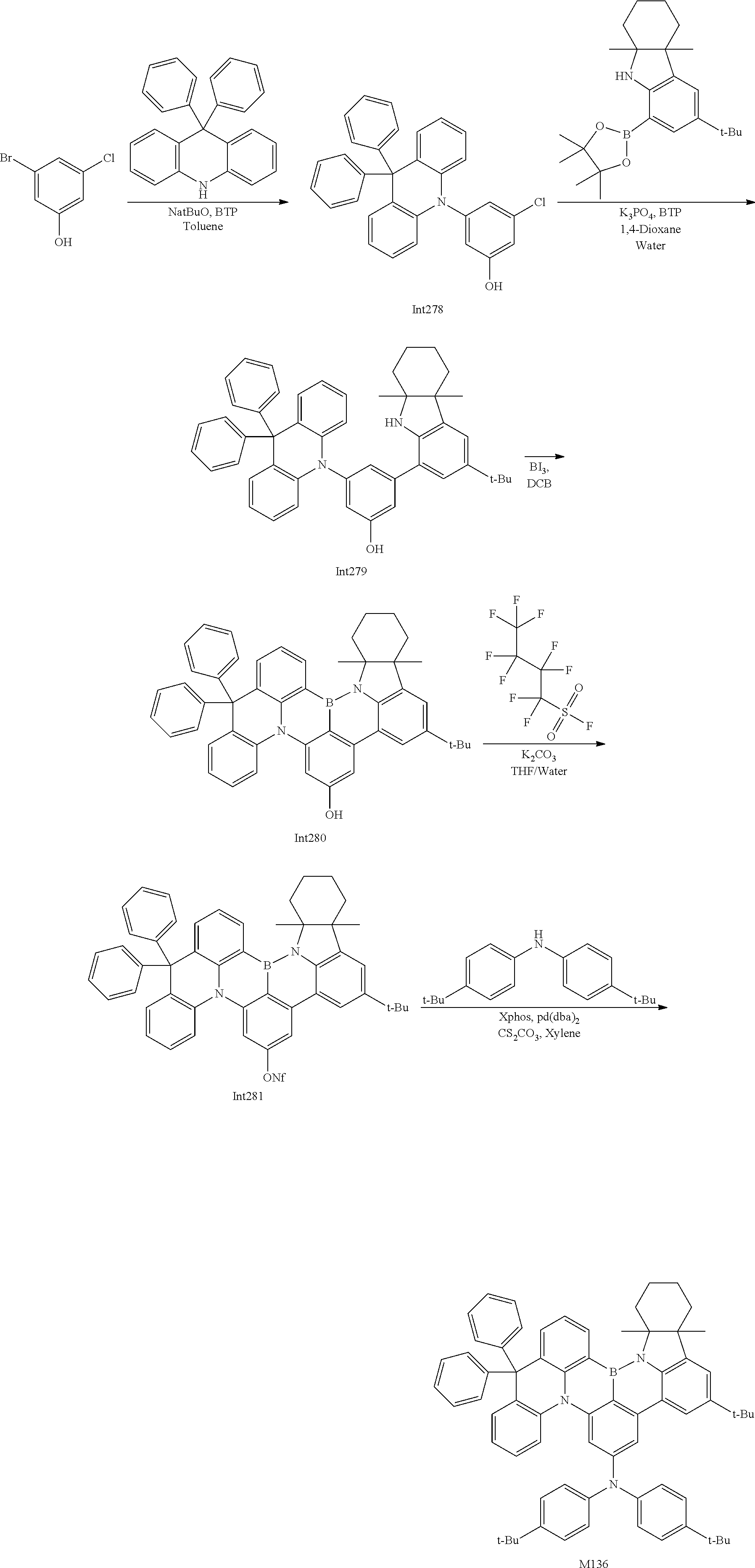

### 1) Synthesis of Int278

The same equivalents and method were used as in the synthesis process of Int266 using 9,9-diphenyl-9,10-dihydroacridine instead of 6-(tert-butyl)-4a,9a-dimethyl-2,3,4,4a,9,9a-hexahydro-1H-carbazole, and the result was recrystallized to obtain Int278 (51 g, yield 77%). MS [M+H]+=461

### 2) Synthesis of Int279

The same equivalents and method were used as in the synthesis process of Int267 using Int278 and 6-(tert-butyl)-4a,9a-dimethyl-8-(4,4,5,5-tetramethyl-1,3,2-dioxaborolan-2-yl)-2,3,4,4a,9,9a-hexahydro-1H-carbazole instead of Int266 and N-([1,1′-biphenyl]-4-yl)-9,9-dimethyl-3-(4,4,5,5-tetramethyl-1,3,2-dioxaborolan-2-yl)-9H-fluoren-2-anine, and the result was recrystallized to obtain Int279 (32.3 g, yield 73%). MS[M+H]+=682

### 3) Synthesis of Int280

Under the nitrogen atmosphere, Int279 (25 g) and boron triiodide (24.4 g) were introduced to 1,2-dichlorobenzene (250 ml), and stirred for 4 hours at 160° C. After the reaction was finished, the result was extracted, and then recrystallized to obtain Int280 (7.3 g, yield 29%). MS[M+H]+=690

### 4) Synthesis of Int281

Int280 (7 g), 1,1,2,2,3,3,4,4,4-nonafluorobutane-1-sulfonyl fluoride (2.8 ml) and potassium carbonate (4.3 g) were introduced to tetrahydrofuran (70 ml) and water (30 ml), and stirred for 2 hours under reflux. After the reaction was finished, the result was extracted, and then column purified to obtain Int281 (9.1 g, yield 92%). MS [M+H]+=972

### 5) Synthesis of Compound M136

Under the nitrogen atmosphere, Int281 (7 g), bis(4-(tert-butyl)phenyl)amine (2.1 g), pd(dba)₂ (0.13 g), Xphos (0.21 g) and cesium carbonate (7.1 g) were introduced to xylene (100 ml), and stirred for 12 hours under reflux. After the reaction was finished, the result was extracted, and then recrystallized to obtain Compound M136 (5.1 g, yield 74%). MS[M+H]+=953

### Synthesis Example 137. Synthesis of Compound M137

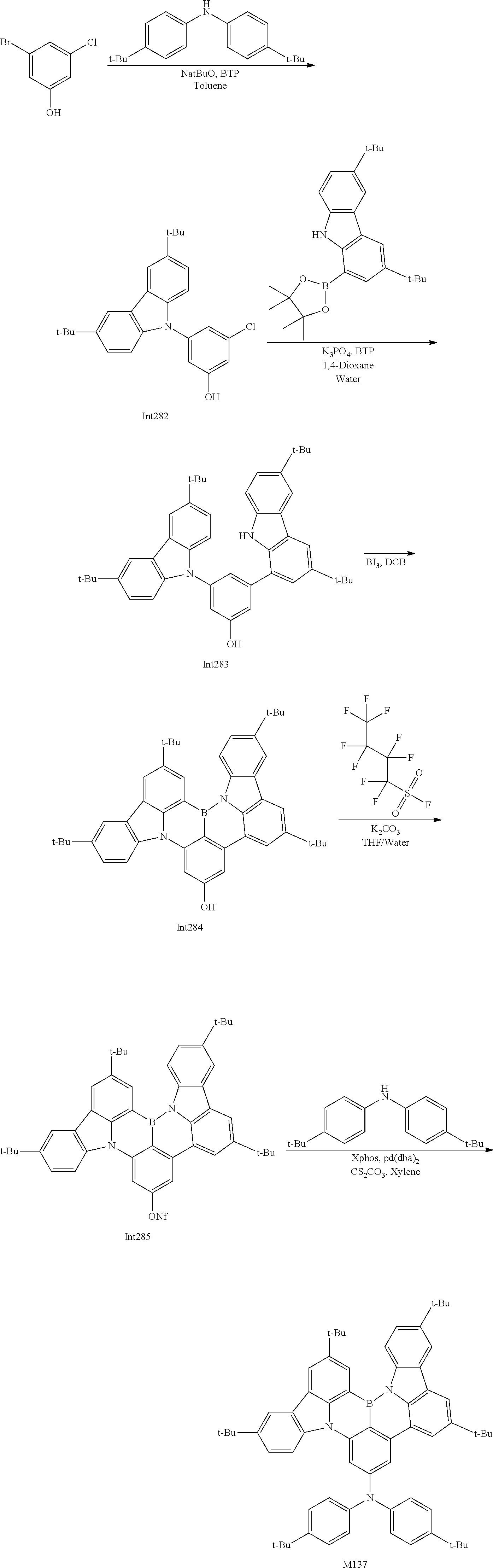

### 1) Synthesis of Int282

The same equivalents and method were used as in the synthesis process of Int266 using 3,6-di-tert-butyl-9H-carbazole instead of 6-(tert-butyl)-4a,9a-dimethyl-2,3,4,4a,9,9a-hexahydro-1H-carbazole, and the result was recrystallized to obtain Int282 (44 g, yield 75%). MS[M+H]+=407

### 2) Synthesis of Int283

The same equivalents and method were used as in the synthesis process of Int267 using Int282 and 2,6-di(tert-butyl)-8-(4,4,5,5-tetramethyl-1,3,2-dioxaborolan-2-yl)-2,3,4,4a,9,9a-hexahydro-1H-carbazole instead of Int266 and N-([1,1′-biphenyl]-4-yl)-9,9-dimethyl-3-(4,4,5,5-tetramethyl-1,3,2-dioxaborolan-2-yl)-9H-fluoren-2-amine, and the result was recrystallized to obtain Int283 (37 g, yield 77%). MS[M+H]+=650

### 3) Synthesis of Int284

Under the nitrogen atmosphere, Int283 (25 g) and boron triiodide (25.6 g) were introduced to 1,2-dichlorobenzene (250 ml), and stirred for 4 hours at 160° C. After the reaction was finished, the result was extracted, and then recrystallized to obtain Int284 (7.2 g, yield 28%). MS[M+H]+=658

### 4) Synthesis of Int285

Int284 (7 g), 1,1,2,2,3,3,4,4,4-nonafluorobutane-1-sulfonyl fluoride (2.9 ml) and potassium carbonate (4.4 g) were introduced to tetrahydrofuran (70 ml) and water (30 ml), and stirred for 2 hours under reflux. After the reaction was finished, the result was extracted, and then column purified to obtain Int285 (9.2 g, yield 92%). MS [M+H]+=940

### 5) Synthesis of Compound M137

Under the nitrogen atmosphere, Int285 (7 g), bis(4-(tert-butyl)phenyl)amine (2.1 g), pd(dba)₂ (0.13 g), Xphos (0.21 g) and cesium carbonate (7.3 g) were introduced to xylene (100 ml), and stirred for 12 hours under reflux. After the reaction was finished, the result was extracted, and then recrystallized to obtain Compound M137 (5.3 g, yield 77%). MS[M+H]+=921

### Synthesis Example 138. Synthesis of Compound M138

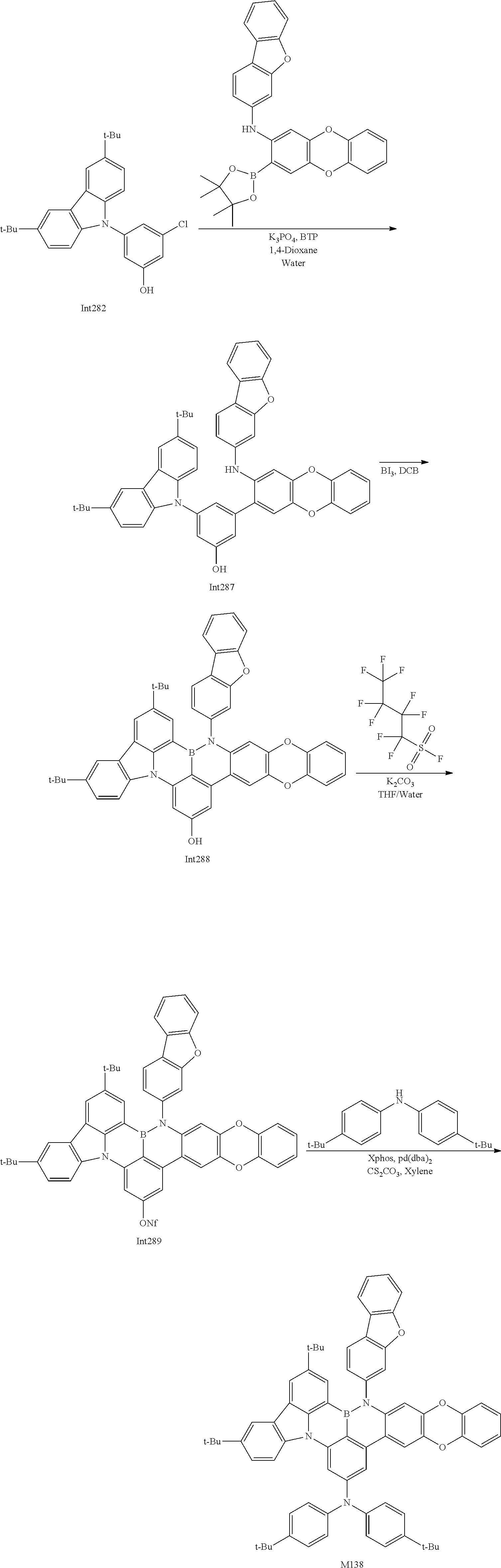

### 1) Synthesis of Int287

The same equivalents and method were used as in the synthesis process of Int267 using Int282 and N-(dibenzo[b,d]furan-3-yl)-3-(4,4,5,5-tetramethyl-1,3,2-dioxaborolan-2-yl)dibenzo[b, e][1, 4]dioxin-2-amine instead of Int266 and N—([1,1′-biphenyl]-4-yl)-9,9-dimethyl-3-(4,4,5,5-tetramethyl-1,3,2-dioxaborolan-2-yl)-9H-fluoren-2-amine, and the result was recrystallized to obtain Int287 (41.2 g, yield 76%). MS[M+H]+=736

### 2) Synthesis of Int288

Under the nitrogen atmosphere, Int287 (25 g) and boron triiodide (22.6 g) were introduced to 1,2-dichlorobenzene (250 ml), and stirred for 4 hours at 160° C. After the reaction was finished, the result was extracted, and then recrystallized to obtain Int288 (7.3 g, yield 29%). MS[M+H]+=734

### 4) Synthesis of Int289

Int288 (7 g), 1,1,2,2,3,3,4,4,4-nonafluorobutane-1-sulfonyl fluoride (2.6 ml) and potassium carbonate (3.9 g) were introduced to tetrahydrofuran (70 ml) and water (30 ml), and stirred for 2 hours under reflux. After the reaction was finished, the result was extracted, and then column purified to obtain Int289 (8.9 g, yield 92%). MS[M+H]+=1026

### 5) Synthesis of Compound M138

Under the nitrogen atmosphere, Int289 (7 g), bis(4-(tert-butyl)phenyl)amine (2.0 g), pd(dba)₂ (0.12 g), Xphos (0.20 g) and cesium carbonate (6.7 g) were introduced to xylene (100 ml), and stirred for 12 hours under reflux. After the reaction was finished, the result was extracted, and then recrystallized to obtain Compound M138 (5.1 g, yield 74%). MS[M+H]+=1007

### Synthesis Example 139. Synthesis of Compound M139

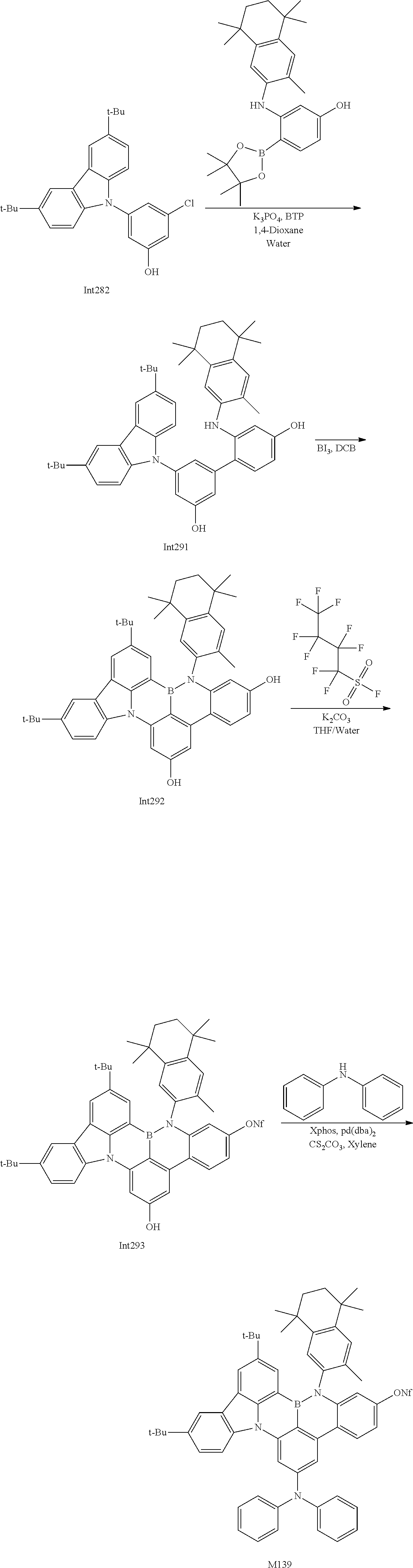

### 1) Synthesis of Int291

The same equivalents and method were used as in the synthesis process of Int267 using Int282 and 3-((3,5,5,8,8-pentamethyl-5,6,7,8-tetrahydronaphthalen-2-yl)amino)-4-(4,4,5,5-tetramethyl-1,3,2-dioxaborolan-2-yl)phenol instead of Int266 and N—([1,1′-biphenyl]-4-yl)-9,9-dimethyl-3-(4,4,5,5-tetramethyl-1,3,2-dioxaborolan-2-yl)-9H-fluoren-2-amine, and the result was recrystallized to obtain Int291 (37.7 g, yield 75%). MS[M+H]+=680

### 2) Synthesis of Int292

Under the nitrogen atmosphere, Int291 (25 g) and boron triiodide (24.5 g) were introduced to 1,2-dichlorobenzene (250 ml), and stirred for 4 hours at 160° C. After the reaction was finished, the result was extracted, and then recrystallized to obtain Int292 (7.3 g, yield 29%). MS[M+H]+=688

### 4) Synthesis of Int293

Int292 (7 g), 1,1,2,2,3,3,4,4,4-nonafluorobutane-1-sulfonyl fluoride (2.8 ml) and potassium carbonate (4.3 g) were introduced to tetrahydrofuran (70 ml) and water (30 ml), and stirred for 2 hours under reflux. After the reaction was finished, the result was extracted, and then column purified to obtain Int293 (9.1 g, yield 92%). MS[M+H]+=970

### 5) Synthesis of Compound M139

Under the nitrogen atmosphere, Int293 (7 g), diphenylamine (2.5 g), pd(dba)₂ (0.17 g), Xphos (0.28 g) and cesium carbonate (9.4 g) were introduced to xylene (100 ml), and stirred for 12 hours under reflux. After the reaction was finished, the result was extracted, and then recrystallized to obtain Compound M139 (5.5 g, yield 77%). MS [M+H]+=990

### Synthesis Example 140. Synthesis of Compound M140

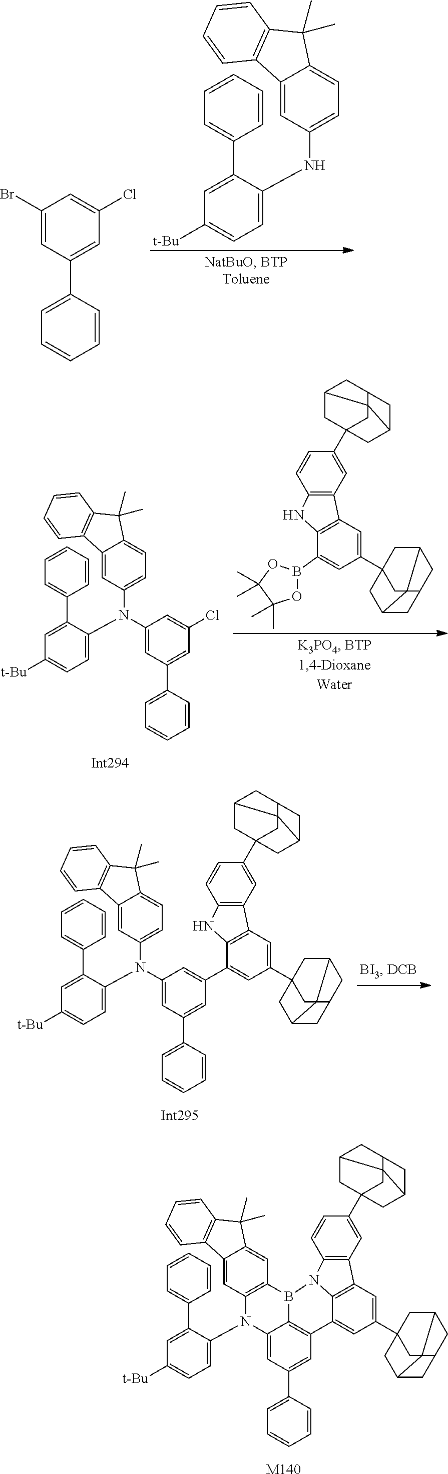

### 1) Synthesis of Int294

The same equivalents and method were used as in the synthesis process of Int1 using N-(5-(tert-butyl)-[1,1′-biphenyl]-2-yl)-9,9-dimethyl-9H-fluoren-3-amine instead of bis(5,5,8,8-tetramethyl-5,6,7,8-tetrahydronaphthalen-2-yl)amine, and after the reaction was finished, the result was extracted and then recrystallized to obtain Int294 (48 g, yield 71%). MS[M+H]+=605

### 2) Synthesis of Int295

The same equivalents and method were used as in the synthesis process of Int2 using Int294 and 3,6-di(adamantan-1-yl)-1-(4,4,5,5-tetramethyl-1,3,2-dioxaborolan-2-yl)-9H-carbazole instead of Int1 and 4-(4,4,5,5-tetramethyl-1,3,2-dioxaborolan-2-yl)-10H-spiro[acridine-9,9′-fluorene], and after the reaction was finished, the result was extracted and then recrystallized to obtain Int295 (36.6 g, yield 73%). MS [M+H]+=1004

### 3) Synthesis of Compound M140

Under the nitrogen atmosphere, Int295 (25 g) and boron triiodide (16.6 g) were introduced to 1,2-dichlorobenzene (250 ml), and stirred for 4 hours at 160° C. After the reaction was finished, the result was extracted, and then recrystallized to obtain Compound M140 (7.4 g, yield 29%). MS[M+H]+=1012

### Synthesis Example 141. Synthesis of Compound M141

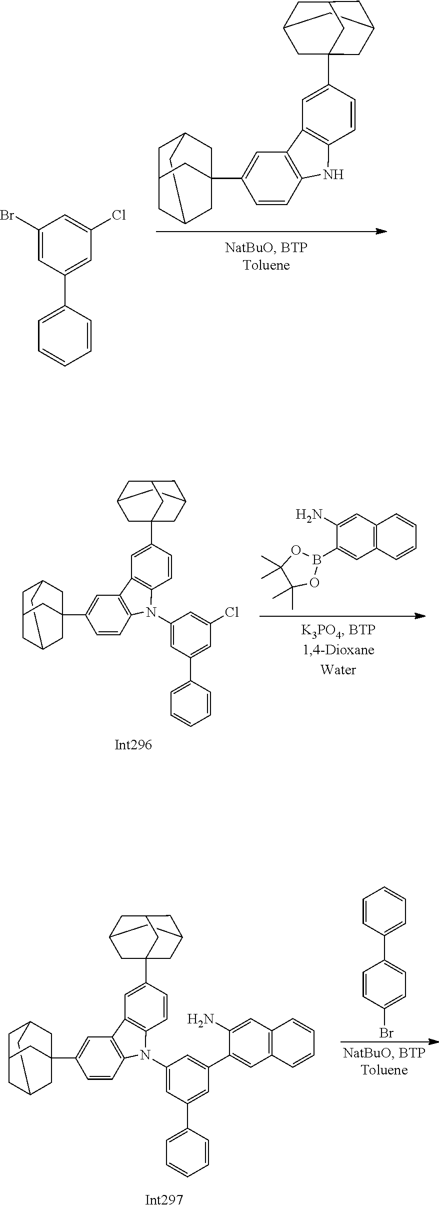 [SMILES: Clc1cc(Br)cc(-c2ccccc2)c1 ; c1cc2[nH]c3ccc(C45CC6CC(CC(C6)C4)C5)cc3c2cc1C12CC3CC(CC(C3)C1)C2 ; Clc1cc(-c2ccccc2)cc(-n2c3ccc(C45CC6CC(CC(C6)C4)C5)cc3c3cc(C45CC6CC(CC(C6)C4)C5)ccc32)c1 ; CC1(C)OB(c2cc3ccccc3cc2N)OC1(C)C ; Nc1cc2ccccc2cc1-c1cc(-c2ccccc2)cc(-n2c3ccc(C45CC6CC(CC(C6)C4)C5)cc3c3cc(C45CC6CC(CC(C6)C4)C5)ccc32)c1 ; Brc1ccc(-c2ccccc2)cc1]

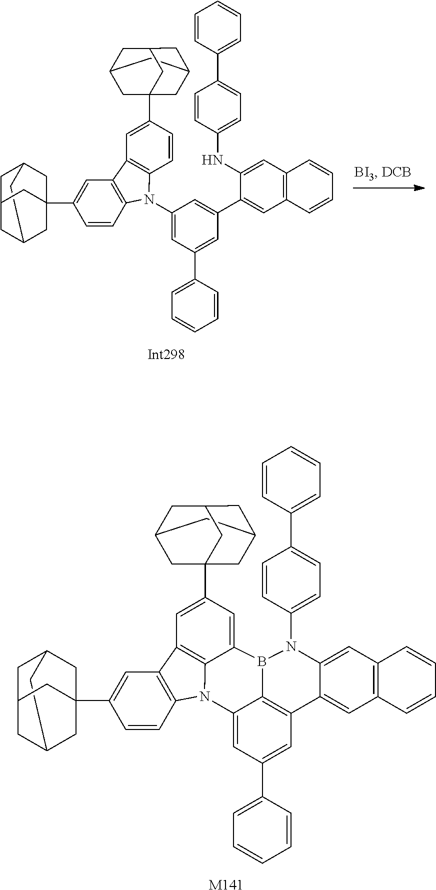

### 1) Synthesis of Int296

The same equivalents and method were used as in the synthesis process of Int1 using 3,6-di(adamantan-1-yl)-9H-carbazole instead of bis(5,5,8,8-tetramethyl-5,6,7,8-tetrahydronaphthalen-2-yl)amine, and after the reaction was finished, the result was extracted and then recrystallized to obtain Int296 (51 g, yield 73%). MS[M+H]+=623

### 2) Synthesis of Int297

The same equivalents and method were used as in the synthesis process of Int2 using Int296 and 3-(4,4,5,5-tetramethyl-1,3,2-dioxaborolan-2-yl)naphthalen-2-amine instead of Int1 and 4-(4,4,5,5-tetramethyl-1,3,2-dioxaborolan-2-yl)-10H-spiro[acridine-9,9′-fluorene], and after the reaction was finished, the result was extracted and then recrystallized to obtain Int297 (27.3 g, yield 78%). MS[M+H]+=730

### 3) Synthesis of Int298

The same equivalents and method were used as in the synthesis process of Int1 using Int297 (27 g) and 4-bromo-1,1′-biphenyl (10.4 g) instead of 3-bromo-5-chloro-1,1′-biphenyl and bis(5,5,8,8-tetramethyl-5,6,7,8-tetrahydronaphthalen-2-yl)amine, and after the reaction was finished, the result was extracted and then recrystallized to obtain Int298 (25.4 g, yield 78%). MS[M+H]+=882

### 4) Synthesis of Compound M141

Under the nitrogen atmosphere, Int298 (25 g) and boron triiodide (18.9 g) were introduced to 1,2-dichlorobenzene (250 ml), and stirred for 4 hours at 160° C. After the reaction was finished, the result was extracted, and then recrystallized to obtain Compound M141 (7.3 g, yield 29%). MS[M+H]+=890

### Synthesis Example 142. Synthesis of Compound M142

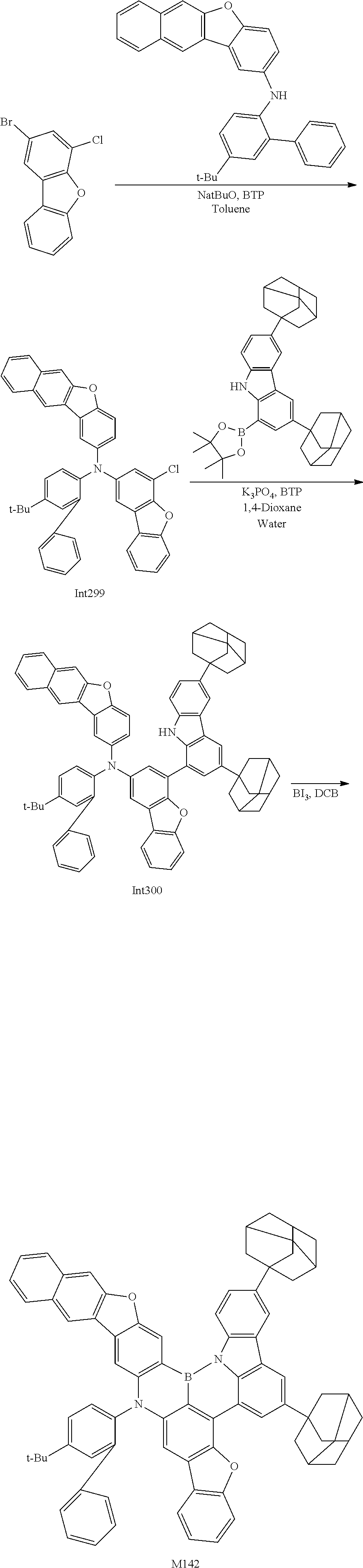

### 1) Synthesis of Int299

The same equivalents and method were used as in the synthesis process of Int134 using N-(5-(tert-butyl)-[1,1′-biphenyl]-2-yl) naphtho[2,3-b]benzofuran-2-amine instead of di([1,1′-biphenyl]-4-yl)amine, and after the reaction was finished, the result was extracted and then recrystallized to obtain Int299 (52.5 g, yield 77%). MS[M+H]+=643

### 2) Synthesis of Int300

The same equivalents and method were used as in the synthesis process of Int135 using Int299 and 3,6-di(adamantan-1-yl)-1-(4,4,5,5-tetramethyl-1,3,2-dioxaborolan-2-yl)-9H-carbazole instead of Int134 and 3,6-di-tert-butyl-1-(4,4,5,5-tetramethyl-1,3,2-dioxaborolan-2-yl)-9H-carbazole, and after the reaction was finished, the result was extracted and then recrystallized to obtain Int300 (36.5 g, yield 75%). MS[M+H]+=1042

### 3) Synthesis of Compound M142

Under the nitrogen atmosphere, Int300 (25 g) and boron triiodide (16 g) were introduced to 1,2-dichlorobenzene (250 ml), and stirred for 4 hours at 160° C. After the reaction was finished, the result was extracted, and then recrystallized to obtain Compound M142 (7.2 g, yield 29%). MS[M+H]+=1050

### Synthesis Example 143. Synthesis of Compound M143

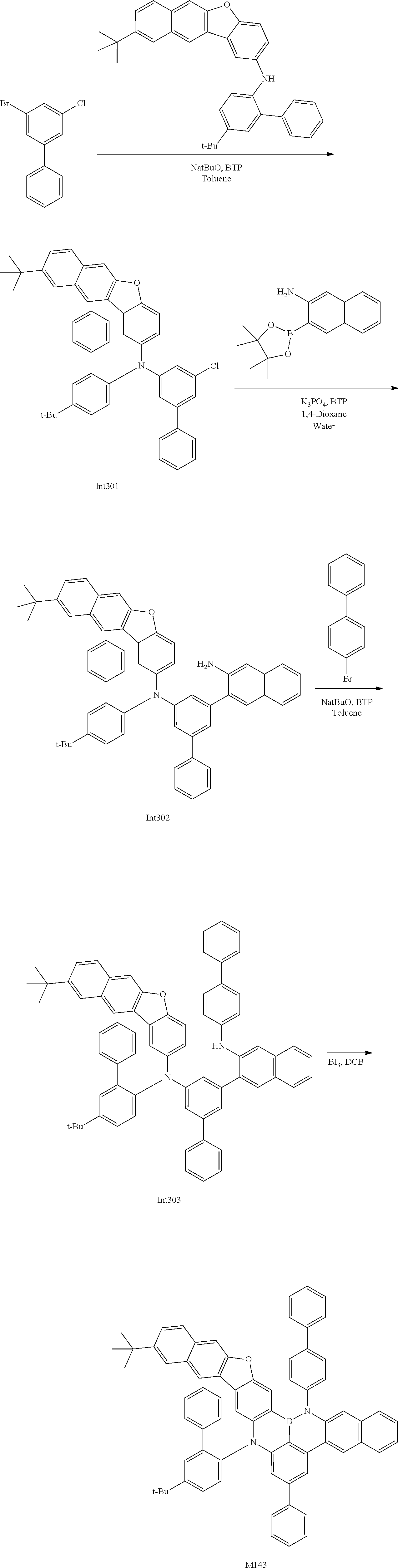

### 1) Synthesis of Int301

The same equivalents and method were used as in the synthesis process of Int1 using 9-(tert-butyl)-N-(5-(tert-butyl)-[1,1′-biphenyl]-2-yl)naphtho[2,3-b]benzofuran-2-amine instead of bis(5,5,8,8-tetramethyl-5,6,7,8-tetrahydronaphthalen-2-yl)amine, and after the reaction was finished, the result was extracted and then recrystallized to obtain Int301 (55.3 g, yield 72%). MS [M+H]+=629

### 2) Synthesis of Int302

The same equivalents and method were used as in the synthesis process of Int2 using Int301 and 3-(4,4,5,5-tetramethyl-1,3,2-dioxaborolan-2-yl)naphthalen-2-amine instead of Int1 and 4-(4,4,5,5-tetramethyl-1,3,2-dioxaborolan-2-yl)-10H-spiro[acridine-9,9′-fluorene], and after the reaction was finished, the result was extracted and then recrystallized to obtain Int302 (27.2 g, yield 78%). MS[M+H]+=792

### 3) Synthesis of Int303

The same equivalents and method were used as in the synthesis process of Int1 using Int302 (27 g) and 4-bromo-1,1′-biphenyl (10.4 g) instead of 3-bromo-5-chloro-1,1′-biphenyl and bis(5,5,8,8-tetramethyl-5,6,7,8-tetrahydronaphthalen-2-yl)amine, and after the reaction was finished, the result was extracted and then recrystallized to obtain Int303 (25.1 g, yield 78%). MS[M+H]+=944

### 4) Synthesis of Compound M143

Under the nitrogen atmosphere, Int303 (25 g) and boron triiodide (17.6 g) were introduced to 1,2-dichlorobenzene (250 ml), and stirred for 4 hours at 160° C. After the reaction was finished, the result was extracted, and then recrystallized to obtain Compound M143 (7.1 g, yield 28%). MS[M+H]+=952

### Synthesis Example 144. Synthesis of Compound M144

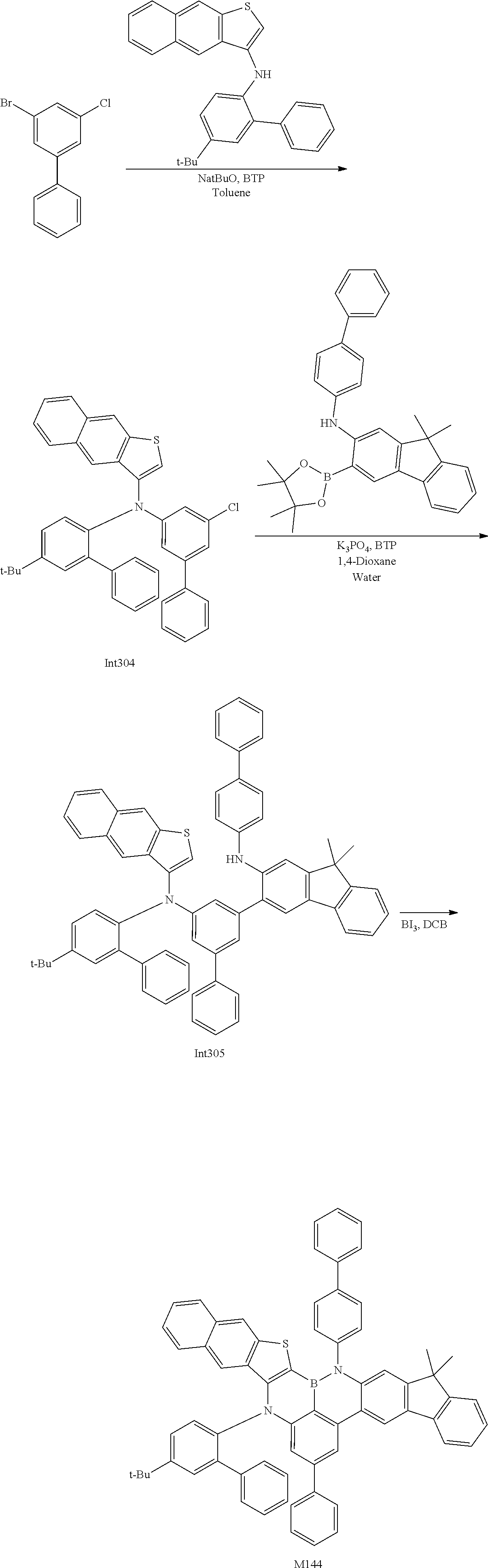

### 1) Synthesis of Int304

The same equivalents and method were used as in the synthesis process of Int1 using N-(5-(tert-butyl)-[1,1′-biphenyl]-2-yl)naphtho[2,3-b]thiophen-3-amine instead of bis(5,5,8,8-tetramethyl-5,6,7,8-tetrahydronaphthalen-2-yl)amine, and after the reaction was finished, the result was extracted and then recrystallized to obtain Int304 (52.2 g, yield 78%). MS[M+H]+=595

### 2) Synthesis of Int305

The same equivalents and method were used as in the synthesis process of Int2 using Int304 and N-([1,1′-biphenyl]-4-yl)-9,9-dimethyl-3-(4,4,5,5-tetramethyl-1,3,2-dioxaborolan-2-yl)-9H-fluoren-2-amine instead of Int1 and 4-(4,4,5,5-tetramethyl-1,3,2-dioxaborolan-2-yl)-10H-spiro[acridine-9,9′-fluorene], and after the reaction was finished, the result was extracted and then recrystallized to obtain Int305 (34.3 g, yield 74%). MS[M+H]+=920

### 3) Synthesis of Compound M144

Under the nitrogen atmosphere, Int305 (25 g) and boron triiodide (18.1 g) were introduced to 1,2-dichlorobenzene (250 ml), and stirred for 4 hours at 160° C. After the reaction was finished, the result was extracted, and then recrystallized to obtain Compound M144 (7.2 g, yield 29%). MS[M+H]+=928

### Synthesis Example 146. Synthesis of Compound M146

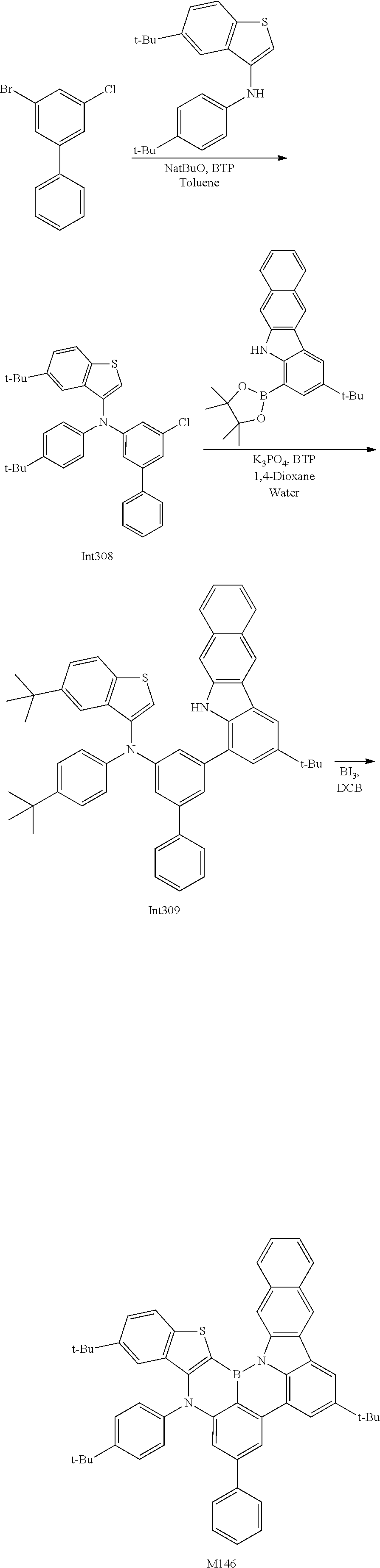

### 1) Synthesis of Int308

The same equivalents and method were used as in the synthesis process of Int1 using 5-(tert-butyl)-N-(4-(tert-butyl)phenyl)benzo[b]thiophen-3-amine instead of bis(5,5,8,8-tetramethyl-5,6,7,8-tetrahydronaphthalen-2-yl)amine, and after the reaction was finished, the result was extracted and then recrystallized to obtain Int308 (44 g, yield 75%). MS[M+H]+=525

### 2) Synthesis of Int309

The same equivalents and method were used as in the synthesis process of Int2 using Int308 and 2-(tert-butyl)-4-(4,4,5,5-tetramethyl-1,3,2-dioxaborolan-2-yl)-5H-benzo[b]carbazole instead of Int1 and 4-(4,4,5,5-tetramethyl-1,3,2-dioxaborolan-2-yl)-10H-spiro[acridine-9,9′-fluorene], and after the reaction was finished, the result was extracted and then recrystallized to obtain Int309 (31.1 g, yield 71%). MS[M+H]+=762

### 3) Synthesis of Compound M146

Under the nitrogen atmosphere, Int309 (25 g) and boron triiodide (21.9 g) were introduced to 1,2-dichlorobenzene (250 ml), and stirred for 4 hours at 160° C. After the reaction was finished, the result was extracted, and then recrystallized to obtain Compound M146 (7.2 g, yield 29%). MS[M+H]+=770

### Synthesis Example 147. Synthesis of Compound M147

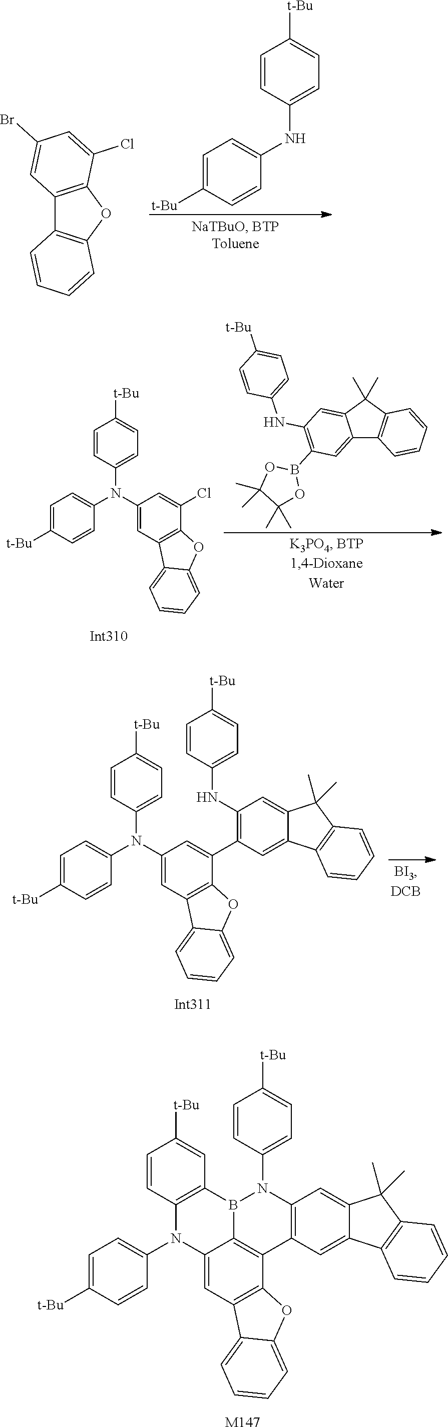

### 1) Synthesis of Int310

The same equivalents and method were used as in the synthesis process of Int134 using bis(4-(tert-butyl)phenyl)amine instead of di([1,1′-biphenyl]-4-yl)amine, and after the reaction was finished, the result was extracted and then recrystallized to obtain Int310 (37 g, yield 72%). MS[M+H]+=483

### 2) Synthesis of Int311

The same equivalents and method were used as in the synthesis process of Int135 using Int310 and N-(4-(tert-butyl)phenyl)-9,9-dimethyl-3-(4,4,5,5-tetramethyl-1,3,2-dioxaborolan-2-yl)-9H-fluoren-2-amine instead of Int134 and 3,6-di-tert-butyl-1-(4,4,5,5-tetramethyl-1,3,2-dioxaborolan-2-yl)-9H-carbazole, and after the reaction was finished, the result was extracted and then recrystallized to obtain Int311 (35.2 g, yield 72%). MS[M+H]+=788

### 3) Synthesis of Compound M147

Under the nitrogen atmosphere, Int311 (25 g) and boron triiodide (21.1 g) were introduced to 1,2-dichlorobenzene (250 ml), and stirred for 4 hours at 160° C. After the reaction was finished, the result was extracted, and then recrystallized to obtain Compound M147 (7.6 g, yield 30%). MS[M+H]+=796

### Synthesis Example 148. Synthesis of Compound M148

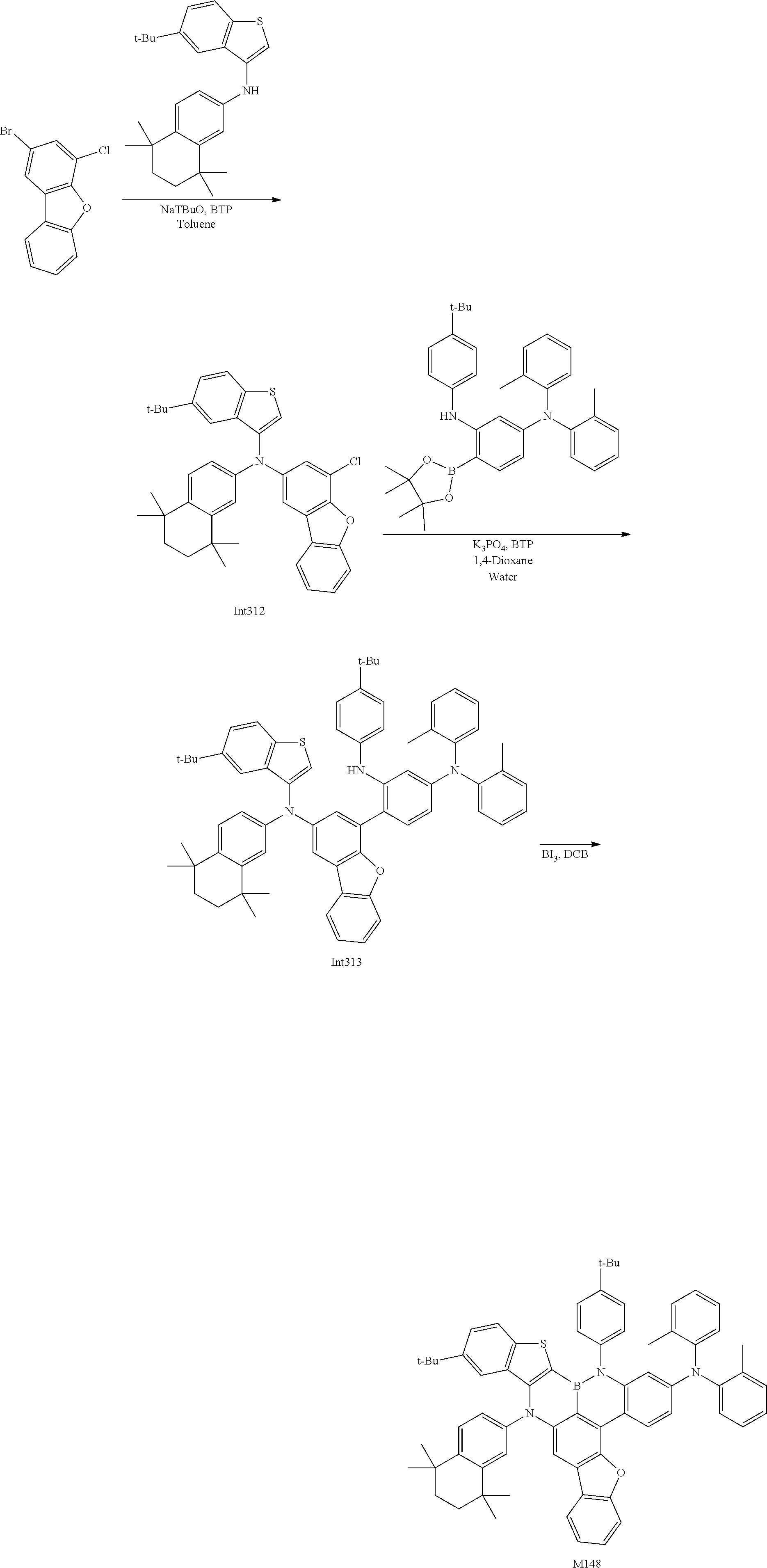

### 1) Synthesis of Int312

The same equivalents and method were used as in the synthesis process of Int134 using 5-(tert-butyl)-N-(5,5,8,8-tetramethyl-5,6,7,8-tetrahydronaphthalen-2-yl)benzo[b]thiophen-3-amine instead of di([1,1′-biphenyl]-4-yl)amine, and after the reaction was finished, the result was extracted and then recrystallized to obtain Int312 (47 g, yield 74%). MS[M+H]+=593

### 2) Synthesis of Int313

The same equivalents and method were used as in the synthesis process of Int135 using Int312 and N3-(4-(tert-butyl)phenyl)-4-(4,4,5,5-tetramethyl-1,3,2-dioxaborolan-2-yl)-N1,N1-di-o-tolylbenzene-1,3-diamine instead of Int134 and 3,6-di-tert-butyl-1-(4,4,5,5-tetramethyl-1,3,2-dioxaborolan-2-yl)-9H-carbazole, and after the reaction was finished, the result was extracted and then recrystallized to obtain Int313 (36.6 g, yield 74%). MS[M+H]+=977

### 3) Synthesis of Compound M148

Under the nitrogen atmosphere, Int313 (25 g) and boron triiodide (17 g) were introduced to 1,2-dichlorobenzene (250 ml), and stirred for 4 hours at 160° C. After the reaction was finished, the result was extracted, and then recrystallized to obtain Compound M148 (7.7 g, yield 31%). MS[M+H]+=985

### Synthesis Example 149. Synthesis of Compound M149

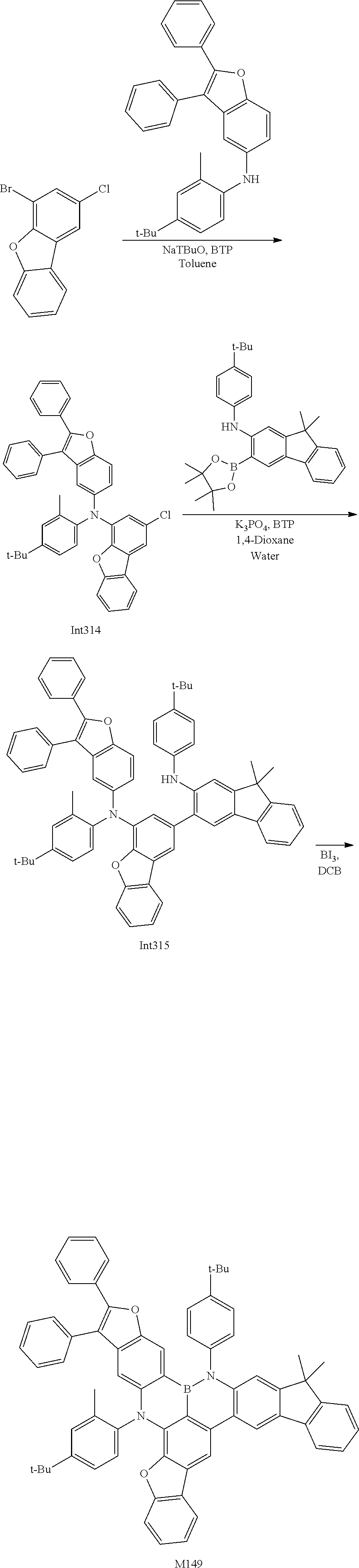

### 1) Synthesis of Int314

The same equivalents and method were used as in the synthesis process of Int158 using N-(4-(tert-butyl)-2-methylphenyl)-2,3-diphenylbenzofuran-5-amine instead of 3,6-di-tert-butyl-9H-carbazole, and after the reaction was finished, the result was extracted and then recrystallized to obtain Int314 (48 g, yield 71%). MS [M+H]+=633

### 2) Synthesis of Int315

The same equivalents and method were used as in the synthesis process of Int135 using Int314 and N-(4-(tert-butyl)phenyl)-9,9-dimethyl-3-(4,4,5,5-tetramethyl-1,3,2-dioxaborolan-2-yl)-9H-fluoren-2-amine instead of Int134 and 3,6-di-tert-butyl-1-(4,4,5,5-tetramethyl-1,3,2-dioxaborolan-2-yl)-9H-carbazole, and after the reaction was finished, the result was extracted and then recrystallized to obtain Int315 (34.2 g, yield 77%). MS[M+H]+=938

### 3) Synthesis of Compound M149

Under the nitrogen atmosphere, Int315 (25 g) and boron triiodide (17.6 g) were introduced to 1,2-dichlorobenzene (250 ml), and stirred for 4 hours at 160° C. After the reaction was finished, the result was extracted, and then recrystallized to obtain Compound M149 (7.8 g, yield 31%). MS[M+H]+=946

### Synthesis Example 150. Synthesis of Compound M150

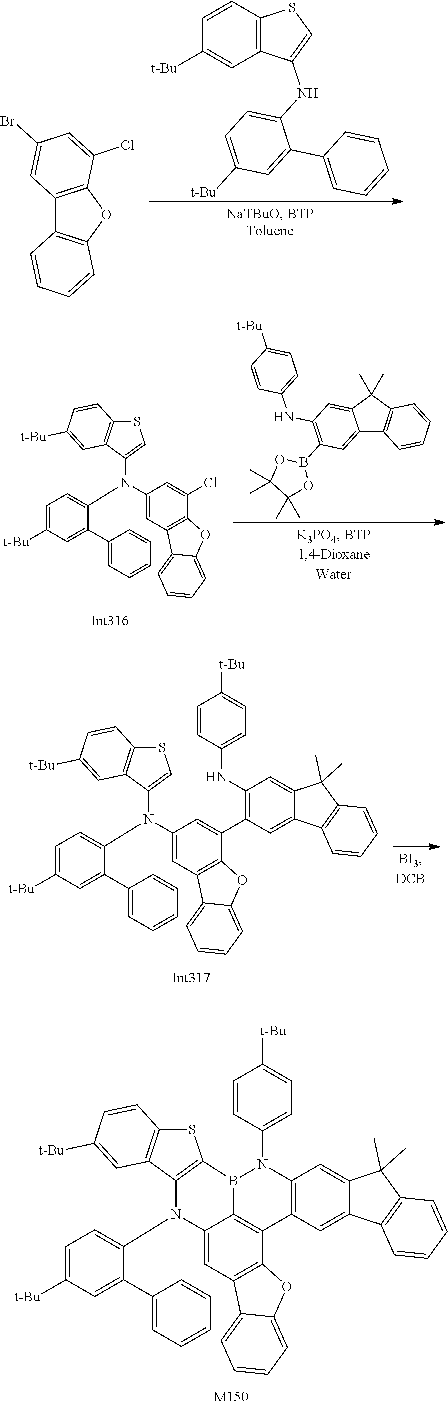

### 1) Synthesis of Int316

The same equivalents and method were used as in the synthesis process of Int134 using 5-(tert-butyl)-N-(5-(tert-butyl)-[1,1′-biphenyl]-2-yl)benzo[b]thiophen-3-amine instead of di([1,1′-biphenyl]-4-yl)amine, and after the reaction was finished, the result was extracted and then recrystallized to obtain Int316 (46 g, yield 70%). MS [M+H]+=615

### 2) Synthesis of Int317

The same equivalents and method were used as in the synthesis process of Int135 using Int316 and N-(4-(tert-butyl)phenyl)-9,9-dimethyl-3-(4,4,5,5-tetramethyl-1,3,2-dioxaborolan-2-yl)-9H-fluoren-2-amine instead of Int134 and 3,6-di-tert-butyl-1-(4,4,5,5-tetramethyl-1,3,2-dioxaborolan-2-yl)-9H-carbazole, and after the reaction was finished, the result was extracted and then recrystallized to obtain Int317 (33.7 g, yield 75%). MS[M+H]+=920

### 3) Synthesis of Compound M150

Under the nitrogen atmosphere, Int317 (25 g) and boron triiodide (18.1 g) were introduced to 1,2-dichlorobenzene (250 ml), and stirred for 4 hours at 160° C. After the reaction was finished, the result was extracted, and then recrystallized to obtain Compound M150 (7.8 g, yield 31%). MS[M+H]+=928

### Experimental Example 1

### Manufacture of Organic Light Emitting Device

### Example 1

A glass substrate on which ITO (indium tin oxide) was coated as a thin film to a thickness of 1,400 Å was placed in detergent-dissolved distilled water and ultrasonic cleaned. Herein, a product of Fischer Co. was used as the detergent, and as the distilled water, distilled water filtered twice with a filter manufactured by Millipore Co. was used. After the ITO was cleaned for 30 minutes, ultrasonic cleaning was repeated twice using distilled water for 10 minutes. After the cleaning with distilled water was finished, the substrate was ultrasonic cleaned with solvents of isopropyl alcohol, acetone and methanol, then dried, and then transferred to a plasma cleaner. In addition, the substrate was cleaned for 5 minutes using oxygen plasma, and then transferred to a vacuum deposition apparatus.

On the transparent ITO electrode prepared as above, the following HI-A and HAT-CN were thermal vacuum deposited to thicknesses of 650 Å and 50 Å, respectively, to form first and second hole injection layers. On the hole injection layer, the following HT-A was vacuum deposited to a thickness of 600 Å to form a hole transfer layer. On the hole transfer layer, the following HT-B was vacuum deposited to a thickness of 50 Å to form an electron blocking layer. Subsequently, a light emitting layer was formed on the electron blocking layer by vacuum depositing Compound M1 of Synthesis Example 1 as a blue light emitting dopant in 4 parts by weight based on 100 parts by weight of the light emitting layer, and the following BH to a thickness of 200 Å as a host. Then, the following Compound ET-A was vacuum deposited to 50 Å on the light emitting layer as a first electron transfer layer, and consecutively, the following ET-B and LiQ were vacuum deposited in a weight ratio of 1:1 to a thickness of 360 Å to form a second electron transfer layer. On the second electron transfer layer, LiQ was vacuum deposited to a thickness of 5 Å to form an electron injection layer. On the electron injection layer, aluminum and silver were deposited in a weight ratio of 10:1 to a thickness of 220 Å, and aluminum was deposited to a thickness of 1000 Å thereon to form a cathode.

In the above-described process, the deposition rates of the organic materials were maintained at 0.4 Å/sec to 0.9 Å/sec, the deposition rate of the aluminum of the cathode was maintained at 2 Å/sec, and the degree of vacuum during the deposition was maintained at 5×10⁻⁸ torr to 1×10⁻⁷ torr to manufacture an organic light emitting device.

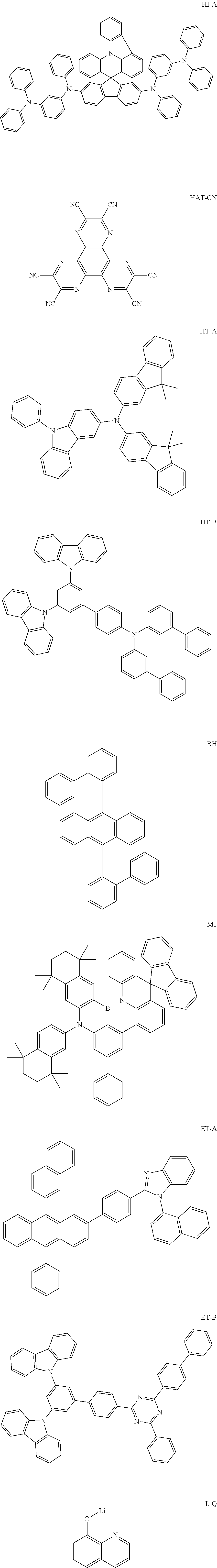

### Examples 2 to 5 and 7 to 16, 18 to 84, 86 to 115, 117 to 128, 130, 131, 133 to 144, 146 to 150 and Comparative Examples 1 to 13

Organic light emitting devices were manufactured in the same manner as in Example 1 except that, as the dopant of the light emitting layer, compounds of the following Table 1 were each used instead of Compound M1.

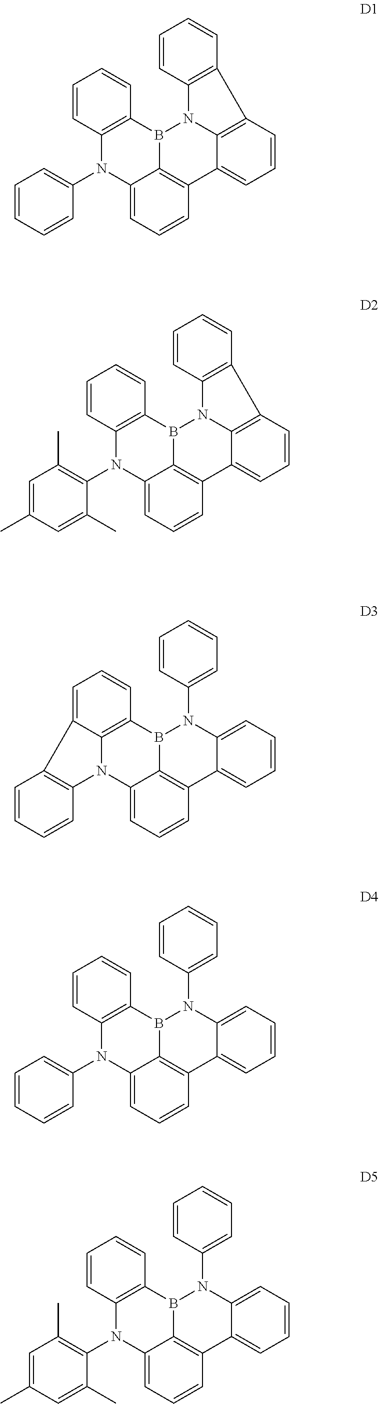 [SMILES: c1ccc(N2c3ccccc3B3c4c(cccc42)-c2cccc4c5ccccc5n3c24)cc1 ; Cc1cc(C)c(N2c3ccccc3B3c4c(cccc42)-c2cccc4c5ccccc5n3c24)c(C)c1 ; c1ccc(N2B3c4c(cccc4-n4c5ccccc5c5cccc3c54)-c3ccccc32)cc1 ; c1ccc(N2B3c4ccccc4N(c4ccccc4)c4cccc(c43)-c3ccccc32)cc1 ; Cc1cc(C)c(N2c3ccccc3B3c4c(cccc42)-c2ccccc2N3c2ccccc2)c(C)c1]

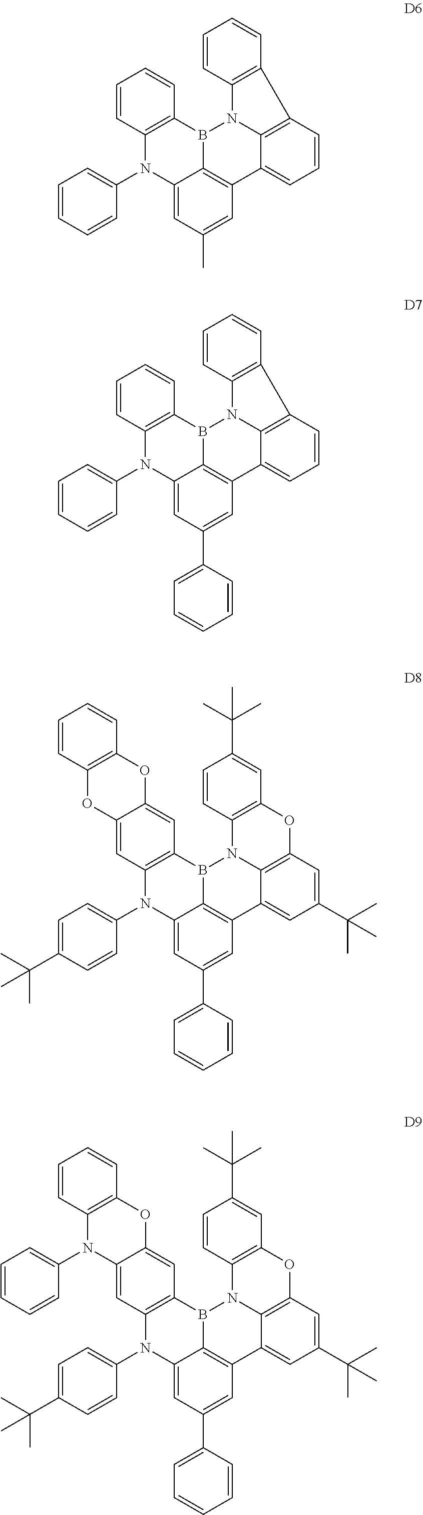

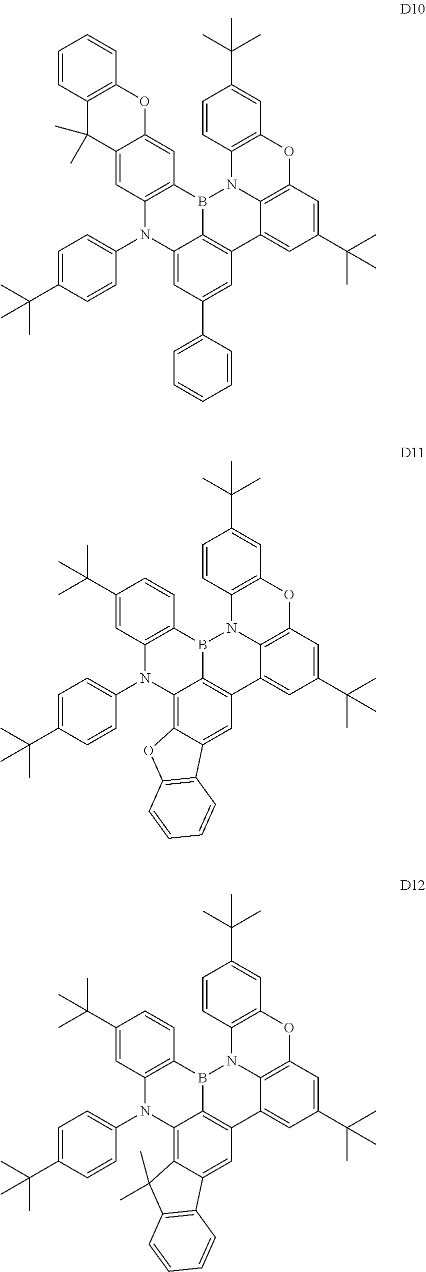

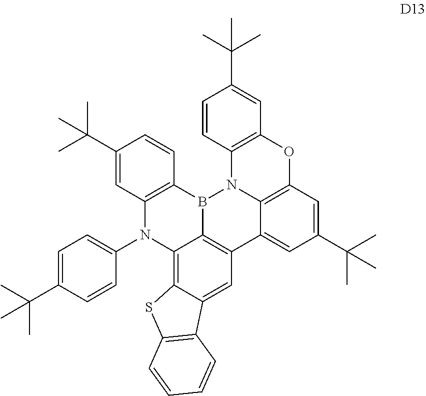 [SMILES: CC(C)(C)c1ccc(N2c3cc(C(C)(C)C)ccc3B3c4c(cc5c(sc6ccccc65)c42)-c2cc(C(C)(C)C)cc4c2N3c2ccc(C(C)(C)C)cc2O4)cc1]

### Evaluation of Device

For each of the organic light emitting devices of Examples 1 to 5, 7 to 16, 18 to 84, 86 to 115, 117 to 128, 130, 131, 133 to 144, 146 to 150 and Comparative Examples 1 to 13, a voltage and conversion efficiency (cd/A/y) when applying current density of 10 mA/cm², and a lifetime (LT₉₅) when applying current density of 20 mA/cm² were measured, and the results are shown in the following Table 1. Herein, T₉ represents time taken for luminance to decrease to 95% when employing initial luminance as 100% at current density of 20 mA/cm².

TABLE 1

| | | conversion | |
|---|---|---|---|
| | voltage | efficiency | lifetime |
| | (V) | (Cd/A/y) | (T95)hr |
| Example 1 (Compound M1) | 3.8 | 62.3 | 273 |
| Example 2 (Compound M2) | 3.7 | 62.1 | 272 |
| Example 3 (Compound M3) | 3.7 | 62.5 | 275 |
| Example 4 (Compound M4) | 3.7 | 64.3 | 278 |
| Example 5 (Compound M5) | 3.7 | 62.5 | 273 |
| Example 7 (Compound M7) | 3.7 | 64.7 | 278 |
| Example 8 (Compound M8) | 3.8 | 63.3 | 277 |
| Example 9 (Compound M9) | 3.8 | 63.2 | 276 |
| Example 10 (Compound M10) | 3.8 | 63.1 | 277 |
| Example 11 (Compound M11) | 3.8 | 63.2 | 277 |
| Example 12 (Compound M12) | 3.7 | 62.4 | 272 |
| Example 13 (Compound M13) | 3.8 | 64.1 | 278 |
| Example 14 (Compound M14) | 3.8 | 63.6 | 277 |
| Example 15 (Compound M15) | 3.8 | 64.8 | 276 |
| Example 16 (Compound M16) | 3.7 | 64.6 | 287 |
| Example 18 (Compound M18) | 3.7 | 64.5 | 277 |
| Example 19 (Compound M19) | 3.7 | 63.6 | 276 |
| Example 20 (Compound M20) | 3.8 | 63.5 | 276 |
| Example 21 (Compound M21) | 3.7 | 63.3 | 275 |
| Example 22 (Compound M22) | 3.8 | 64 | 279 |
| Example 23 (Compound M23) | 3.7 | 64.1 | 277 |
| Example 24 (Compound M24) | 3.7 | 64.5 | 278 |
| Example 25 (Compound M25) | 3.8 | 64.3 | 278 |
| Example 26 (Compound M26) | 3.8 | 62.2 | 272 |
| Example 27 (Compound M27) | 3.7 | 62.3 | 273 |
| Example 28 (Compound M28) | 3.8 | 64.6 | 278 |
| Example 29 (Compound M29) | 3.7 | 64.2 | 279 |
| Example 30 (Compound M30) | 3.8 | 63.3 | 277 |
| Example 31 (Compound M31) | 3.7 | 64.2 | 279 |
| Example 32 (Compound M32) | 3.7 | 64.5 | 277 |
| Example 33 (Compound M33) | 3.7 | 64.1 | 278 |
| Example 34 (Compound M34) | 3.7 | 64.4 | 277 |
| Example 35 (Compound M35) | 3.7 | 64.7 | 277 |
| Example 36 (Compound M36) | 3.7 | 63.3 | 276 |
| Example 37 (Compound M37) | 3.7 | 63.2 | 277 |
| Example 38 (Compound M38) | 3.7 | 62.4 | 272 |
| Example 39 (Compound M39) | 3.7 | 63.5 | 275 |
| Example 40 (Compound M40) | 3.7 | 64.4 | 278 |
| Example 41 (Compound M41) | 3.8 | 62.9 | 274 |
| Example 42 (Compound M42) | 3.8 | 62.8 | 271 |
| Example 43 (Compound M43) | 3.8 | 61.1 | 272 |
| Example 44 (Compound M44) | 3.8 | 63.9 | 275 |
| Example 45 (Compound M45) | 3.7 | 61.8 | 273 |
| Example 46 (Compound M46) | 3.7 | 61.8 | 274 |
| Example 47 (Compound M47) | 3.8 | 63.3 | 276 |
| Example 48 (Compound M48) | 3.8 | 63.4 | 275 |
| Example 49 (Compound M49) | 3.8 | 64.5 | 279 |
| Example 50 (Compound M50) | 3.8 | 62.3 | 271 |
| Example 51 (Compound M51) | 3.7 | 64.2 | 277 |
| Example 52 (Compound M52) | 3.8 | 63.4 | 276 |
| Example 53 (Compound M53) | 3.7 | 63.6 | 276 |
| Example 54 (Compound M54) | 3.8 | 60.4 | 283 |
| Example 55 (Compound M55) | 3.7 | 62.1 | 273 |
| Example 56 (Compound M56) | 3.7 | 62.3 | 282 |
| Example 57 (Compound M57) | 3.7 | 62.2 | 271 |
| Example 58 (Compound M58) | 3.7 | 62.8 | 273 |
| Example 59 (Compound M59) | 3.7 | 62.7 | 274 |
| Example 60 (Compound M60) | 3.7 | 64.1 | 278 |
| Example 61 (Compound M61) | 3.7 | 62.2 | 273 |
| Example 62 (Compound M62) | 3.8 | 62.9 | 275 |
| Example 63 (Compound M63) | 3.8 | 62.7 | 273 |
| Example 64 (Compound M64) | 3.8 | 64.4 | 278 |
| Example 65 (Compound M65) | 3.8 | 62.2 | 272 |
| Example 66 (Compound M66) | 3.7 | 62.3 | 272 |
| Example 67 (Compound M67) | 3.8 | 62.4 | 273 |
| Example 68 (Compound M68) | 3.8 | 64.4 | 278 |
| Example 69 (Compound M69) | 3.5 | 63.4 | 282 |
| Example 70 (Compound M70) | 3.6 | 65.5 | 288 |
| Example 71 (Compound M71) | 3.6 | 65.5 | 289 |
| Example 72 (Compound M72) | 3.6 | 64.4 | 283 |
| Example 73 (Compound M73) | 3.5 | 64.3 | 282 |
| Example 74 (Compound M74) | 3.6 | 63.5 | 285 |
| Example 75 (Compound M75) | 3.5 | 65.5 | 288 |
| Example 76 (Compound M76) | 3.6 | 63.4 | 281 |
| Example 77 (Compound M77) | 3.5 | 64.4 | 287 |
| Example 78 (Compound M78) | 3.6 | 62.4 | 281 |
| Example 79 (Compound M79) | 3.5 | 63.9 | 283 |
| Example 80 (Compound M80) | 3.6 | 65.6 | 289 |
| Example 81 (Compound M81) | 3.5 | 65.4 | 288 |
| Example 82 (Compound M82) | 3.6 | 63.2 | 284 |
| Example 83 (Compound M83) | 3.5 | 63.4 | 283 |
| Example 84 (Compound M84) | 3.5 | 65.4 | 287 |
| Example 86 (Compound M86) | 3.6 | 64.2 | 285 |
| Example 87 (Compound M87) | 3.6 | 65.5 | 289 |
| Example 88 (Compound M88) | 3.6 | 65.3 | 288 |
| Example 89 (Compound M89) | 3.5 | 65.2 | 288 |
| Example 90 (Compound M90) | 3.5 | 65.3 | 287 |
| Example 91 (Compound M91) | 3.5 | 65.4 | 288 |
| Example 92 (Compound M92) | 3.6 | 63.2 | 281 |
| Example 93 (Compound M93) | 3.5 | 62.3 | 281 |
| Example 94 (Compound M94) | 3.6 | 64.5 | 285 |
| Example 95 (Compound M95) | 3.5 | 64.6 | 284 |
| Example 96 (Compound M96) | 3.6 | 65.2 | 288 |
| Example 97 (Compound M97) | 3.5 | 63.3 | 281 |
| Example 98 (Compound M98) | 3.6 | 65.4 | 289 |
| Example 99 (Compound M99) | 3.5 | 64.2 | 286 |
| Example 100 (Compound M100) | 3.6 | 63.3 | 285 |
| Example 101 (Compound M101) | 3.5 | 61.3 | 282 |
| Example 102 (Compound M102) | 3.6 | 64.2 | 288 |
| Example 103 (Compound M103) | 3.5 | 65.5 | 289 |
| Example 104 (Compound M104) | 3.6 | 65.3 | 289 |
| Example 105 (Compound M105) | 3.7 | 62.3 | 283 |
| Example 106 (Compound M106) | 3.7 | 61.4 | 283 |
| Example 107 (Compound M107) | 3.8 | 62.3 | 281 |
| Example 108 (Compound M108) | 3.7 | 62.2 | 282 |
| Example 109 (Compound M109) | 3.8 | 63.4 | 286 |
| Example 110 (Compound M110) | 3.7 | 64.3 | 288 |
| Example 111 (Compound M111) | 3.8 | 64.2 | 287 |
| Example 112 (Compound M112) | 3.7 | 64.4 | 287 |
| Example 113 (Compound M113) | 3.8 | 62.3 | 283 |
| Example 114 (Compound M114) | 3.7 | 62.8 | 282 |
| Example 115 (Compound M115) | 3.8 | 64.3 | 288 |
| Example 117 (Compound M117) | 3.7 | 63.3 | 284 |
| Example 118 (Compound M118) | 3.8 | 62.4 | 284 |
| Example 119 (Compound M119) | 3.8 | 62.9 | 284 |
| Example 120 (Compound M120) | 3.8 | 64.4 | 288 |
| Example 121 (Compound M121) | 3.8 | 64.2 | 288 |
| Example 122 (Compound M122) | 3.7 | 64.3 | 287 |
| Example 123 (Compound M123) | 3.8 | 63.2 | 285 |
| Example 124 (Compound M124) | 3.7 | 64.4 | 287 |
| Example 125 (Compound M125) | 3.8 | 64.1 | 288 |
| Example 126 (Compound M126) | 3.7 | 64.5 | 288 |
| Example 127 (Compound M127) | 3.8 | 62.3 | 282 |
| Example 128 (Compound M128) | 3.7 | 64.5 | 289 |
| Example 130 (Compound M130) | 3.7 | 64.5 | 289 |
| Example 131 (Compound M131) | 3.8 | 62.9 | 282 |
| Example 133 (Compound M133) | 3.7 | 65.4 | 289 |
| Example 134 (Compound M134) | 3.8 | 65.2 | 289 |
| Example 135 (Compound M135) | 3.8 | 65.4 | 287 |
| Example 136 (Compound M136) | 3.7 | 65.5 | 289 |
| Example 137 (Compound M137) | 3.7 | 65.3 | 287 |
| Example 138 (Compound M138) | 3.7 | 63.8 | 285 |
| Example 139 (Compound M139) | 3.7 | 64.3 | 288 |
| Example 140 (Compound M140) | 3.7 | 64.2 | 277 |
| Example 141 (Compound M141) | 3.7 | 61.2 | 278 |
| Example 142 (Compound M142) | 3.5 | 65.4 | 288 |
| Example 143 (Compound M143) | 3.8 | 62 | 283 |
| Example 144 (Compound M144) | 3.7 | 64.3 | 287 |
| Example 145 (Compound M145) | 3.7 | 64.2 | 289 |
| Example 146 (Compound M146) | 3.7 | 64.5 | 277 |
| Example 147 (Compound M147) | 3.6 | 65.5 | 289 |
| Example 148 (Compound M148) | 3.6 | 64.8 | 285 |
| Example 149 (Compound M149) | 3.7 | 65.1 | 289 |
| Example 150 (Compound M150) | 3.6 | 65.1 | 287 |
| Comparative Example 1 | 4.2 | 51.1 | 205 |
| (Compound D1) | | | |
| Comparative Example 2 | 4.2 | 51.0 | 204 |
| (Compound D2) | | | |
| Comparative Example 3 | 4.3 | 52.3 | 205 |
| (Compound D3) | | | |
| Comparative Example 4 | 4.2 | 50.4 | 202 |
| (Compound D4) | | | |
| Comparative Example 5 | 4.2 | 50.3 | 203 |
| (Compound D5) | | | |
| Comparative Example 6 | 4.2 | 51.3 | 204 |
| (Compound D6) | | | |
| Comparative Example 7 | 4.2 | 51.2 | 204 |
| (Compound D7) | | | |
| Comparative Example 8 | 4.5 | 45.1 | 211 |
| (Compound D8) | | | |
| Comparative Example 9 | 4.6 | 45.5 | 212 |
| (Compound D9) | | | |
| Comparative Example 10 | 4.5 | 46.2 | 213 |
| (Compound D10) | | | |
| Comparative Example 11 | 4.6 | 49.1 | 216 |
| (Compound D11) | | | |
| Comparative Example 12 | 4.5 | 48.3 | 216 |
| (Compound D12) | | | |
| Comparative Example 13 | 4.5 | 47.4 | 216 |
| (Compound D13) | | | |

The conversion efficiency (cd/A/y) considers color purity of a material (CIEy) as well in current efficiency (cd/A), and is an important reference value of efficiency in small and large organic light emitting devices aiming for high luminance and high color gamut.

In Table 1, it was identified that the organic light emitting device according to one embodiment of the present specification had more superior driving voltage, conversion efficiency and lifetime compared to the organic light emitting devices of Comparative Examples 1 to 5 using the compound in which Z1 to Z3 are hydrogen.

In addition, it was identified that the organic light emitting device according to one embodiment of the present specification had more superior driving voltage, conversion efficiency and lifetime compared to the organic light emitting devices of Comparative Examples 6 and 7 using the compound in which Ar1 is a phenyl group, A1 is substituted or unsubstituted benzene, R6 to R8 are hydrogen, adjacent groups among Z1 to Z3 do not bond to form a substituted or unsubstituted ring, and Ar2 and R5 form an unsubstituted indole group at the same time.

In addition, it was identified that the organic light emitting device according to one embodiment of the present specification had more superior driving voltage, conversion efficiency and lifetime compared to the organic light emitting devices of Comparative Examples 8 to 13 using the compound in which Ar2 and R5 form a substituted benzoxazine ring.

### Experimental Example 2

### MD Calculation (Calculation of Distance Between Molecules in Host-Dopant System)

### Example 2-1

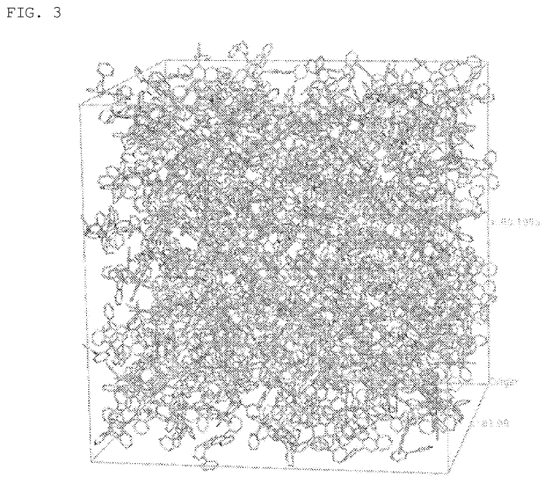

A system including the following Dopant B (dopant) and Compound BH of Example 1 (host) in a weight ratio of 5:95 was obtained. Specifically, 300 molecules (ratio of host 95% and dopant 5%), a temperature of 300K and a simulation time of 3 ns were set using an OPLS3e force field, and through NVT and NPT calculations, an environment of the doped device was computation chemically obtained by calculating molecular dynamics, and the obtained molecular model is shown in FIG. 3.

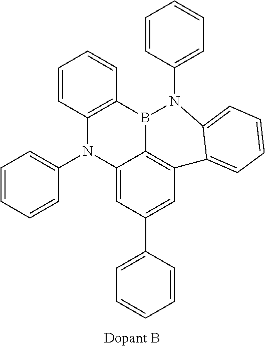 [SMILES: c1ccc(-c2cc3c4c(c2)N(c2ccccc2)c2ccccc2B4N(c2ccccc2)c2ccccc2-3)cc1]

### Comparative Examples 2-1 and 2-2

Molecular systems were calculated in the same manner as in Example 2-1 except that dopants described in the following Table 2 were used instead of Dopant B.

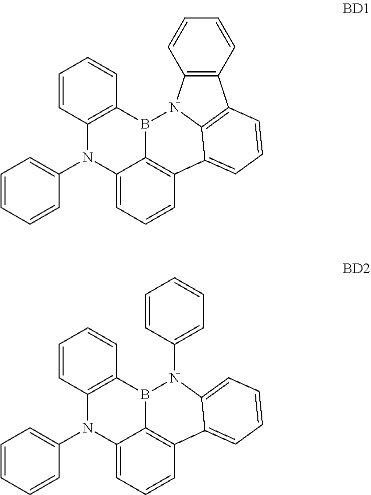 [SMILES: c1ccc(N2c3ccccc3B3c4c(cccc42)-c2cccc4c5ccccc5n3c24)cc1 ; c1ccc(N2B3c4ccccc4N(c4ccccc4)c4cccc(c43)-c3ccccc32)cc1]

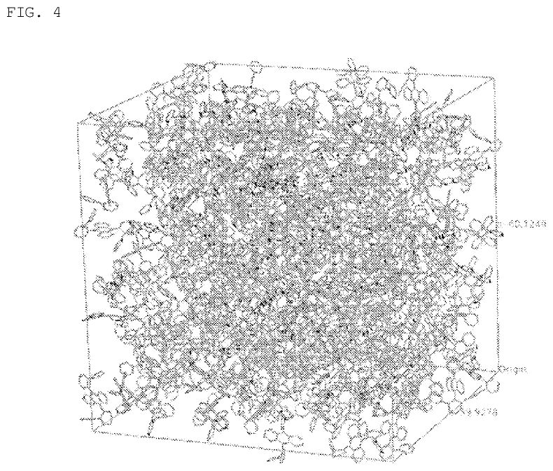

Specifically, FIG. 4 is a diagram illustrating a molecular model obtained by a simulation of a BD1 and BH system of Comparative Example 2-1.

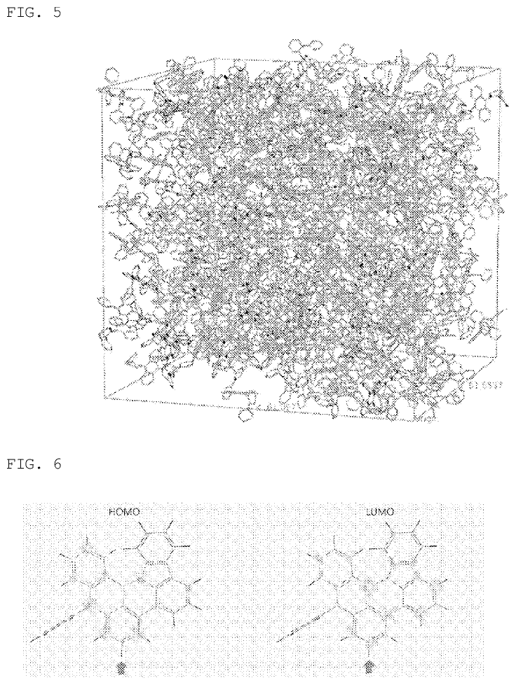

FIG. 5 is a diagram illustrating a molecular model obtained by a simulation of a BD2 and BH system of Comparative Example 2-2.

Calculated average distance values between the dopant and the host molecules of Example 2-1, and Comparative Examples 2-1 and 2-2 are shown in the following Table 2.

TABLE 2

| | | Average Distance Between |
|---|---|---|
| | Dopant | Molecules (Å) |
| Example 2-1 | Dopant B | 15.71 |
| Comparative Example 2-1 | BD1 | 15.21 |
| Comparative Example 2-2 | BD2 | 15.27 |

According to Table 2 and FIG. 3 to FIG. 6, it was identified that Dopant B, a compound in which at least one of Z1 to Z3 of Chemical Formula 1 according to one embodiment of the present specification includes a substituent, had a longer distance between the host and the dopant of the light emitting layer compared to BD1, a compound in which Z1 to Z3 are hydrogen, Ar1 is a phenyl group, A1 is benzene, R6 to R8 are hydrogen and Ar2 and R5 form an unsubstituted indole group, and BD2, a compound in which Z1 to Z3 are hydrogen, Ar1 and Ar2 are a phenyl group, A1 is benzene and R5 to R8 are hydrogen. When materials are concentrated in one space, a Dexter transition occurs between dopant and host materials or dopant and dopant materials, and quenching occurs between triplet electrons and singlet electrons. This means that smooth energy transfer does not occur, and an organic light emitting device has decreased efficiency. Specifically, FIG. 6 is a diagram showing orbital distribution of HOMO and LUMO of BD1, and when examining the structure of BD1, it is seen that the HOMO orbital is present abundantly in the lower benzene ring of B (boron) indicated by the arrow, and the LUMO orbital is present abundantly in the B (boron) atom and the lower benzene ring of B (boron) indicated by the arrow, and particularly, the portion corresponding to the para position of B (boron) is an unstable portion. As above, a very unstable portion is present in the lower benzene ring of B (boron) indicated by the arrow affected by both B (boron) and N (nitrogen). Accordingly, by at least one of Z1 to Z3 having a substituent other than hydrogen, Chemical Formula 1 of the present specification is capable of enhancing efficiency of an organic light emitting device by stabilizing the structure with no unstable portion. In addition, this also closely affect a lifetime of an organic light emitting device, and an organic light emitting device using an unstable material such as BD1, a compound in which Z1 to Z3 are hydrogen, Ar1 is a phenyl group, A1 is benzene, R6 to R8 are hydrogen and Ar2 and R5 form an unsubstituted indole group, and BD2, a compound in which Z1 to Z3 are hydrogen, Ar1 and Ar2 are a phenyl group, A1 is benzene and R5 to R8 are hydrogen, has a reduced lifetime. In addition, when a rapidly degraded portion is present much, a driving voltage increases due to the properties of an organic light emitting device dependent on hopping between molecules.

However, when a distance between molecules increases and an unstable portion is removed as in the compound of Chemical Formula 1 of the present specification, injection of electrons and holes is reduced suppressing quenching and degradation, and as a result, an organic light emitting device has increased efficiency, an enhanced device lifetime, and a reduced voltage as well.

Accordingly, through the experiments of Experimental Examples 1 and 2, it was identified that the organic light emitting device using the compound of Chemical Formula 1 according to one embodiment of the present specification had properties of low driving voltage, high efficiency and long lifetime.

1. A compound represented by the following Chemical Formula 1: 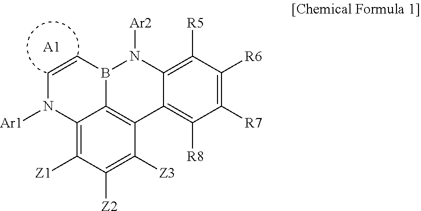
wherein in Chemical Formula 1,
A1 one selected from the group consisting of a substituted or unsubstituted aromatic hydrocarbon ring; a substituted or unsubstituted aliphatic hydrocarbon ring; a substituted or unsubstituted heteroring; and a fused ring thereof,
R5 to R8 are the same as or different from each other, and each independently hydrogen; deuterium; a halogen group; a cyano group; a substituted or unsubstituted alkyl group; a substituted or unsubstituted cycloalkyl group; a substituted or unsubstituted alkoxy group; a substituted or unsubstituted arylalkyl group; a substituted or unsubstituted aryloxy group; a substituted or unsubstituted silyl group; a substituted or unsubstituted amine group; a substituted or unsubstituted aryl group; a substituted or unsubstituted fused ring group of an aromatic hydrocarbon ring and an aliphatic hydrocarbon ring; or a substituted or unsubstituted heterocyclic group, or bond to adjacent groups among R5 to R8 to form a substituted or unsubstituted ring,
Ar1 is a substituted or unsubstituted cycloalkyl group; a substituted or unsubstituted aryl group; a substituted or unsubstituted fused ring group of an aromatic hydrocarbon ring and an aliphatic hydrocarbon ring; or a substituted or unsubstituted heterocyclic group, or bonds to A1 to form one selected from the group consisting of an aromatic heteroring, an aliphatic heteroring, and a fused ring thereof, each of which is substituted or unsubstituted and includes one or more selected from N, S, O and Si,
Ar2 is a substituted or unsubstituted cycloalkyl group; a substituted or unsubstituted aryl group; a substituted or unsubstituted fused ring group of an aromatic hydrocarbon ring and an aliphatic hydrocarbon ring; or a substituted or unsubstituted heterocyclic group, or bonds to R5 to form one selected from the group consisting of an aromatic heteroring, an aliphatic heteroring, and a fused ring thereof, each of which is substituted or unsubstituted and includes one or more selected from N, S, O and Si,
when Ar2 and R5 form a benzoxazine ring, the benzoxazine ring is an unsubstituted benzoxazine ring,
at least one of Z1 to Z3 is deuterium; a halogen group; a cyano group; a substituted or unsubstituted alkyl group; a substituted or unsubstituted cycloalkyl group; a substituted or unsubstituted alkoxy group; a substituted or unsubstituted arylalkyl group; a substituted or unsubstituted aryloxy group; a substituted or unsubstituted silyl group; a substituted or unsubstituted amine group; a substituted or unsubstituted aryl group; a substituted or unsubstituted fused ring group of an aromatic hydrocarbon ring and an aliphatic hydrocarbon ring; or a substituted or unsubstituted heterocyclic group, or adjacent groups among Z1 to Z3 bond to each other to form a substituted or unsubstituted ring, and the rest are hydrogen, and
when Ar1 is a phenyl group, and A1 is substituted or unsubstituted benzene, and R6 to R8 are hydrogen, and adjacent groups among Z1 to Z3 do not bond to each other to form a substituted or unsubstituted ring, and Ar2 and R5 form an indole group at the same time, the indole group is a substituted indole group.

2. The compound of claim 1, wherein the compound of Chemical Formula 1 is represented by the following Chemical Formula 1-1: 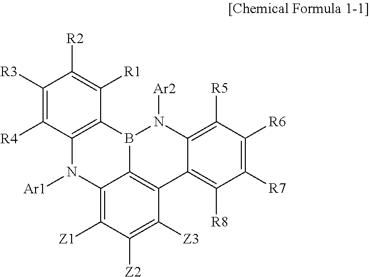
wherein in Chemical Formula 1-1,
R5 to R8, Ar2 and Z1 to Z3 have the same definitions as in Chemical Formula 1,
R1 to R4 are the same as or different from each other, and each independently hydrogen; deuterium; a halogen group; a cyano group; a substituted or unsubstituted alkyl group; a substituted or unsubstituted cycloalkyl group; a substituted or unsubstituted alkoxy group; a substituted or unsubstituted arylalkyl group; a substituted or unsubstituted aryloxy group; a substituted or unsubstituted silyl group; a substituted or unsubstituted amine group; a substituted or unsubstituted aryl group; a substituted or unsubstituted fused ring group of an aromatic hydrocarbon ring and an aliphatic hydrocarbon ring; or a substituted or unsubstituted heterocyclic group, or bond to adjacent groups among R1 to R4 to form one selected from the group consisting of a substituted or unsubstituted aromatic hydrocarbon ring; a substituted or unsubstituted aliphatic hydrocarbon ring; a substituted or unsubstituted heteroring; and a fused ring thereof,
Ar1 is a substituted or unsubstituted cycloalkyl group; a substituted or unsubstituted aryl group; a substituted or unsubstituted fused ring group of an aromatic hydrocarbon ring and an aliphatic hydrocarbon ring; or a substituted or unsubstituted heterocyclic group, or bonds to R4 to form one selected from the group consisting of an aromatic heteroring, an aliphatic heteroring, and a fused ring thereof, each of which is substituted or unsubstituted and includes one or more selected from N, S, O and Si, and
when Ar1 is a phenyl group, and R1 to R4 and R6 to R8 are hydrogen, and adjacent groups among Z1 to Z3 do not bond to each other to form a substituted or unsubstituted ring, and Ar2 and R5 form an indole group at the same time, the indole group is a substituted indole group.

3. The compound of claim 1, wherein Chemical Formula 1 is represented by the following Chemical Formula 1-2: 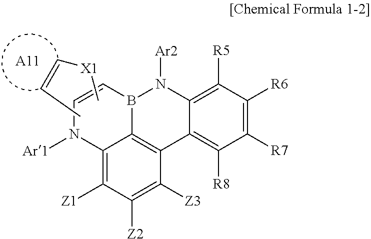
in Chemical Formula 1-2,
R5 to R8, Ar2 and Z1 to Z3 have the same definitions as in Chemical Formula 1,
X1 is CRR′, O or S,
A11 is a substituted or unsubstituted aromatic hydrocarbon ring; a substituted or unsubstituted aliphatic hydrocarbon ring; or a substituted or unsubstituted fused ring of an aromatic hydrocarbon ring and an aliphatic hydrocarbon ring,
Ar′1 is a substituted or unsubstituted cycloalkyl group; a substituted or unsubstituted aryl group; a substituted or unsubstituted fused ring group of an aromatic hydrocarbon ring and an aliphatic hydrocarbon ring; or a substituted or unsubstituted heterocyclic group, and
R and R′ are the same as or different from each other, and each independently a substituted or unsubstituted alkyl group; a substituted or unsubstituted aryl group; or a substituted or unsubstituted heterocyclic group, or bond to each other to form a substituted or unsubstituted ring.

4. The compound of claim 2, wherein the compound of Chemical Formula 1-1 is represented by one of the following Chemical Formulae 1-1-1 to 1-1-36: 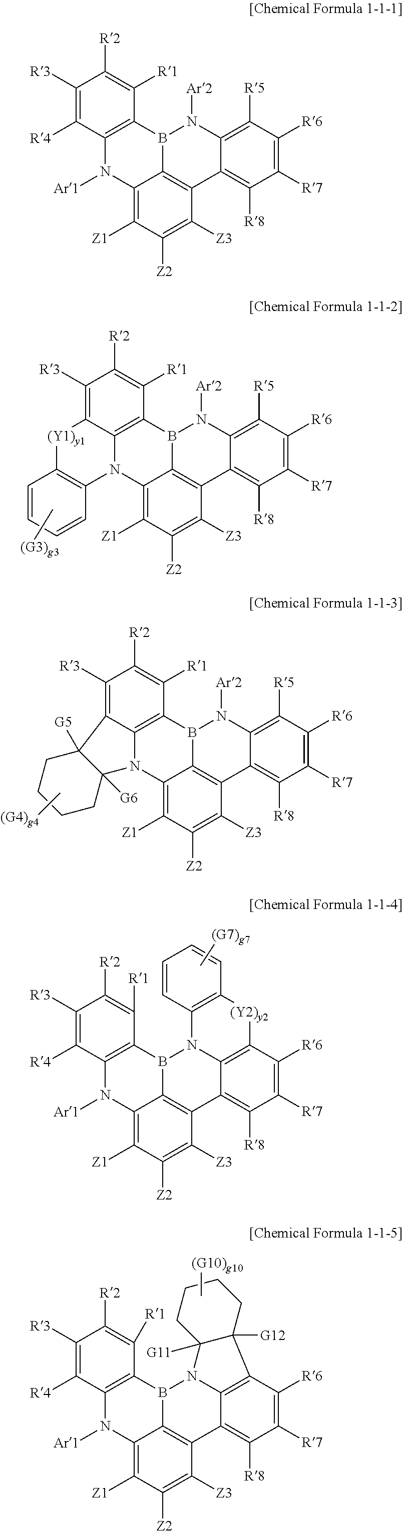 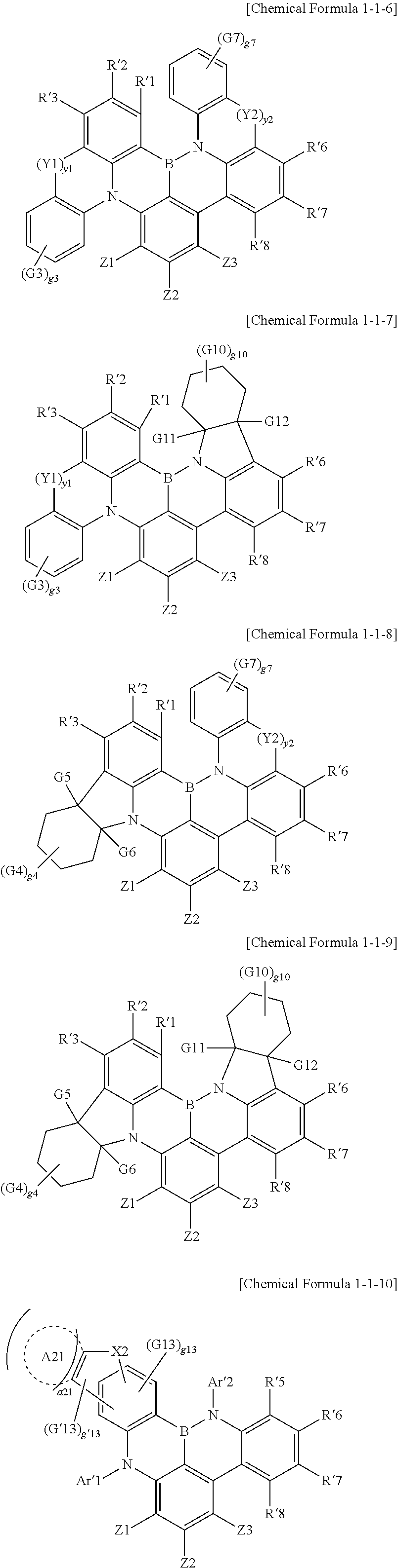 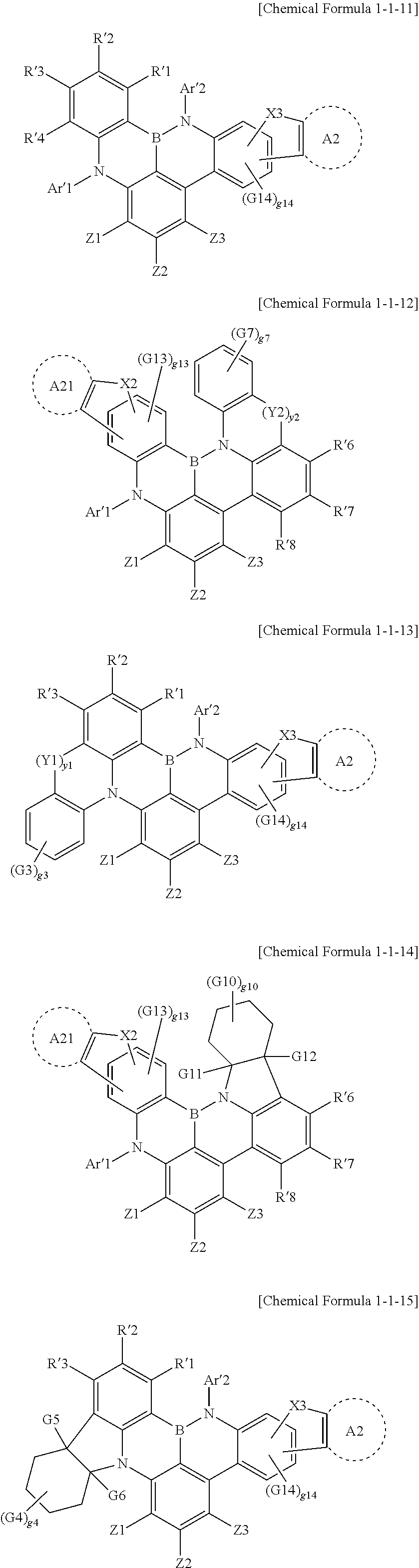 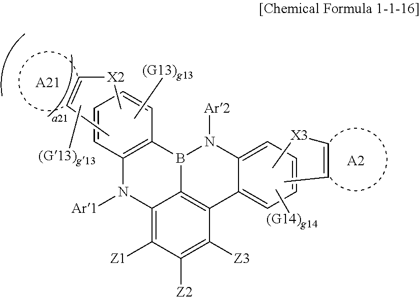 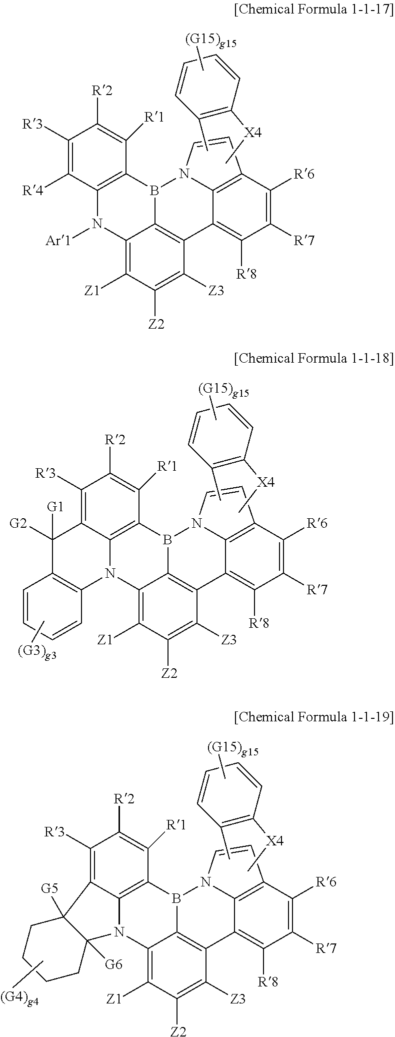 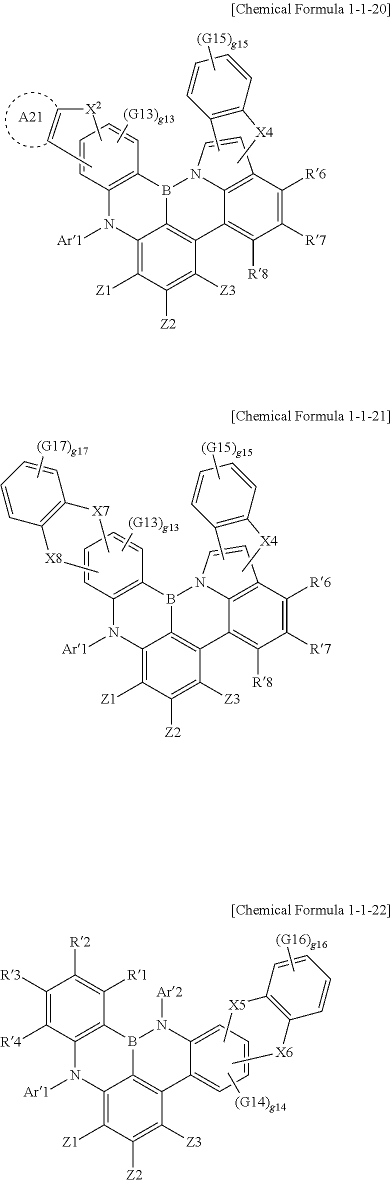 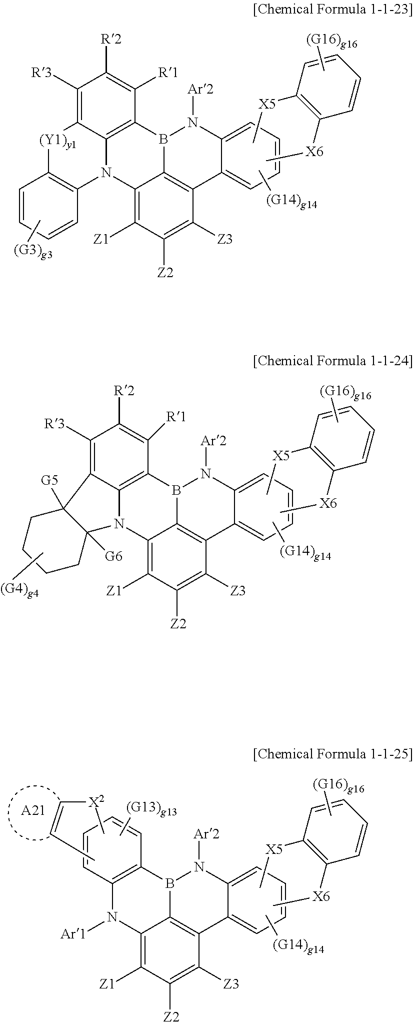 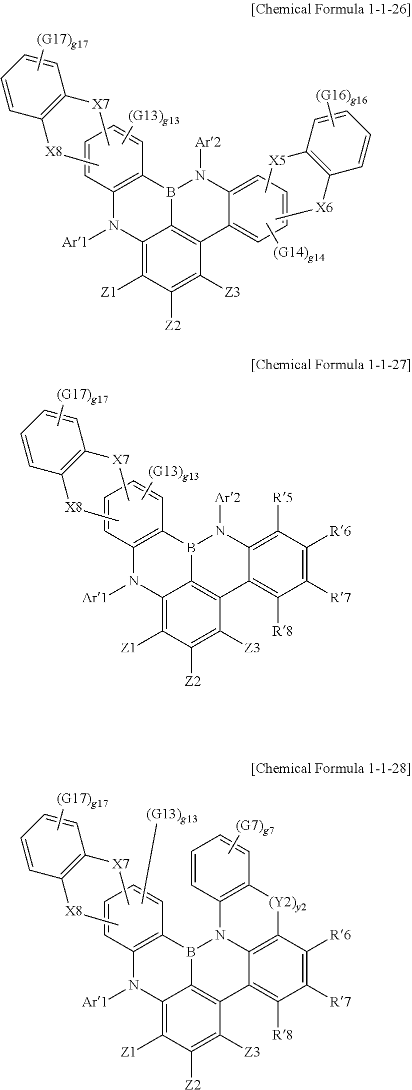 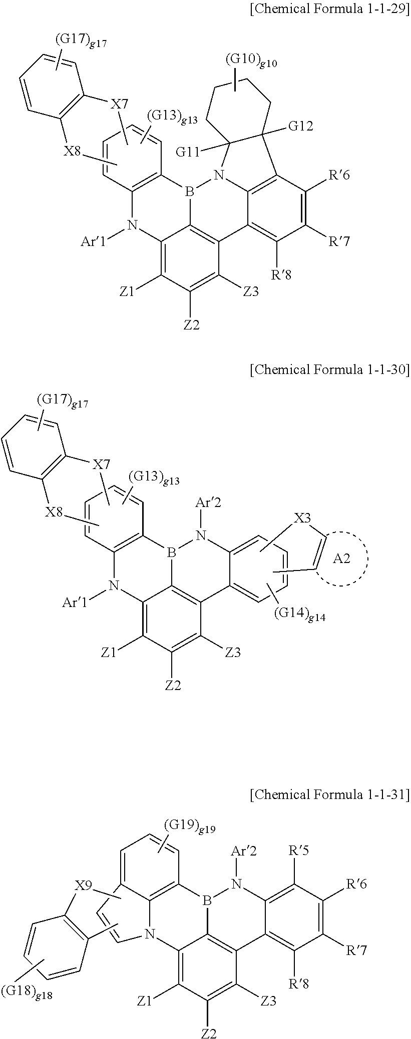 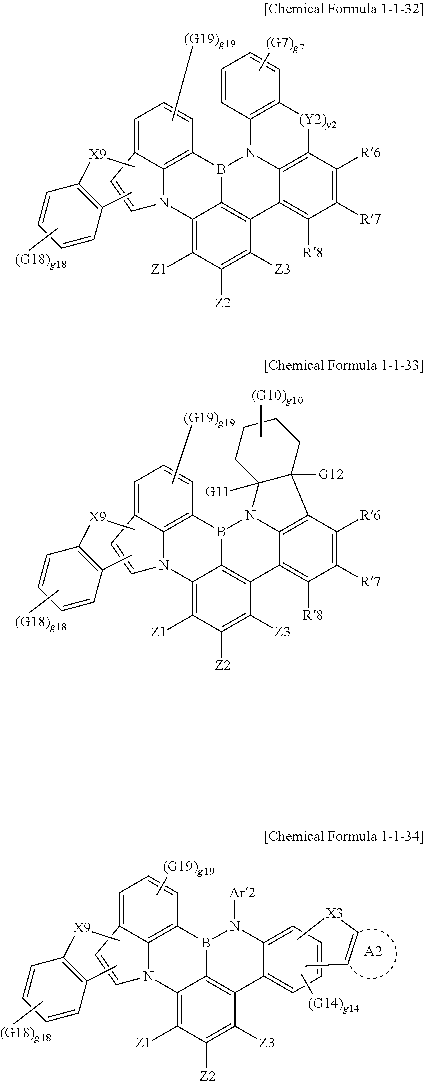 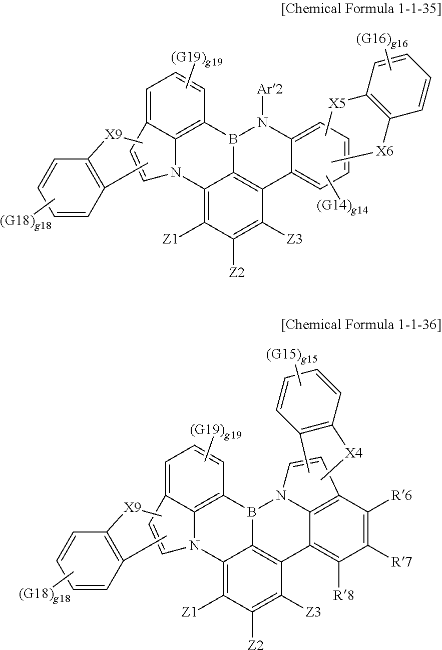
wherein in Chemical Formulae 1-1-1 to 1-1-36,
X2 to X9 are the same as or different from each other, and each independently CRR′, NR″, O or S,
Y1 and Y2 are the same as or different from each other, and each independently CG1G2, SiG8G9, NG101, O or S,
y1 is 0 or 1, and when y1 is 0, Y1 is a direct bond,
y2 is 0 or 1, and when y2 is 0, Y2 is a direct bond,
R, R′ and R″ are the same as or different from each other, and each independently a substituted or unsubstituted alkyl group; a substituted or unsubstituted aryl group; or a substituted or unsubstituted heterocyclic group, or bond to each other to form a substituted or unsubstituted ring,
R′1 to R′8 are the same as or different from each other, and each independently hydrogen; deuterium; a halogen group; a cyano group; a substituted or unsubstituted alkyl group; a substituted or unsubstituted cycloalkyl group; a substituted or unsubstituted alkoxy group; a substituted or unsubstituted arylalkyl group; a substituted or unsubstituted aryloxy group; a substituted or unsubstituted silyl group; a substituted or unsubstituted amine group; a substituted or unsubstituted aryl group; a substituted or unsubstituted fused ring group of an aromatic hydrocarbon ring and an aliphatic hydrocarbon ring; or a substituted or unsubstituted heterocyclic group,
G1 to G19, G′13 and G101 are the same as or different from each other, and each independently hydrogen; deuterium; a halogen group; a cyano group; a substituted or unsubstituted alkyl group; a substituted or unsubstituted cycloalkyl group; a substituted or unsubstituted alkoxy group; a substituted or unsubstituted arylalkyl group; a substituted or unsubstituted aryloxy group; a substituted or unsubstituted silyl group; a substituted or unsubstituted amine group; a substituted or unsubstituted aryl group; a substituted or unsubstituted fused ring group of an aromatic hydrocarbon ring and an aliphatic hydrocarbon ring; or a substituted or unsubstituted heterocyclic group, or adjacent groups bond to each other to form a substituted or unsubstituted aromatic hydrocarbon ring; a substituted or unsubstituted aliphatic hydrocarbon ring; or a substituted or unsubstituted fused ring of an aromatic hydrocarbon ring and an aliphatic hydrocarbon ring,
g3, g7, and g15 to g18 are each an integer of 1 to 4,
g4 and g10 are each an integer of 1 to 8,
g13 and g14 are each 1 or 2,
g′13 is an integer of 0 to 2,
g19 is an integer of 1 to 3,
a21 is 0 or 1,
when g3, g4, g7, g10, and g15 to g19 are each 2 or greater, substituents in the two or more parentheses are the same as or different from each other, when g13, g′13 and g14 are each 2, substituents in the two parentheses are the same as or different from each other,
Ar′1 and Ar′2 are the same as or different from each other, and each independently a substituted or unsubstituted cycloalkyl group; a substituted or unsubstituted aryl group; a substituted or unsubstituted fused ring group of an aromatic hydrocarbon ring and an aliphatic hydrocarbon ring; or a substituted or unsubstituted heterocyclic group,
A2 and A21 are the same as or different from each other, and each independently a substituted or unsubstituted aromatic hydrocarbon ring; a substituted or unsubstituted aliphatic hydrocarbon ring; or a substituted or unsubstituted fused ring of an aromatic hydrocarbon ring and an aliphatic hydrocarbon ring,
at least one of Z1 to Z3 is deuterium; a halogen group; a cyano group; a substituted or unsubstituted alkyl group; a substituted or unsubstituted cycloalkyl group; a substituted or unsubstituted alkoxy group; a substituted or unsubstituted arylalkyl group; a substituted or unsubstituted aryloxy group; a substituted or unsubstituted silyl group; a substituted or unsubstituted amine group; a substituted or unsubstituted aryl group; a substituted or unsubstituted fused ring group of an aromatic hydrocarbon ring and an aliphatic hydrocarbon ring; or a substituted or unsubstituted heterocyclic group, or bonds to adjacent groups to form a substituted or unsubstituted ring, and the rest are hydrogen, and
wherein in Chemical Formulae 1-1-4, 1-1-6, 1-1-8, 1-1-12, 1-1-28 and 1-1-32,
when y2 is 1 and Y2 is O, G7 and R′6 to R′8 are hydrogen.

5. The compound of claim 3, wherein the compound of Chemical Formula 1-2 is represented by one of the following Chemical Formulae 1-2-1 to 1-2-6: 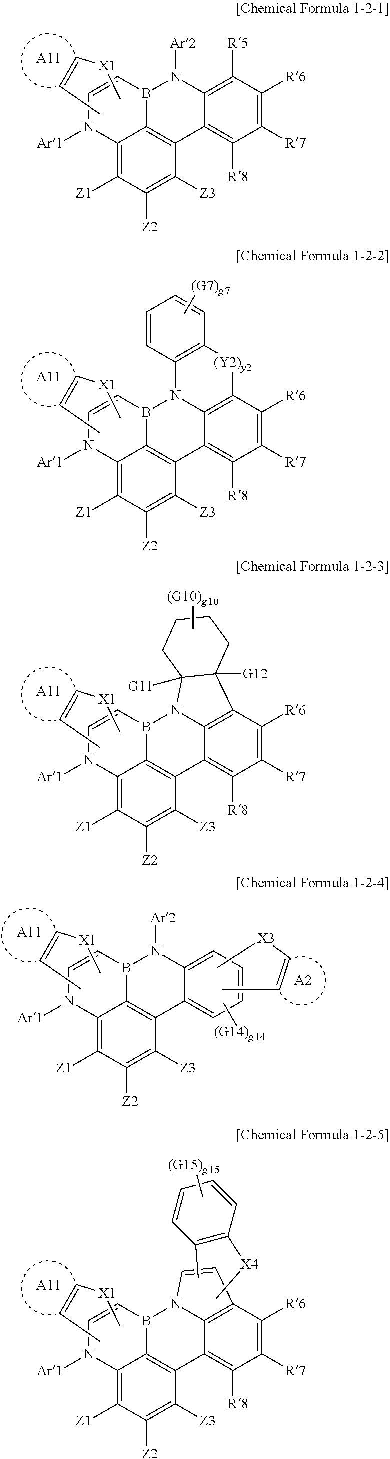 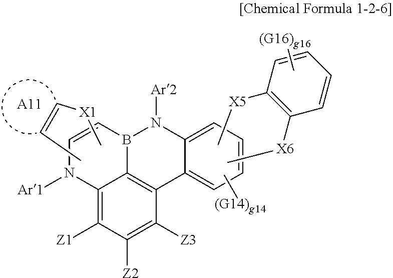
wherein in Chemical Formulae 1-2-1 to 1-2-6,
X1, A11 and Z1 to Z3 have the same definitions as in Chemical Formula 1-2,
X3 to X6 are the same as or different from each other, and each independently CRR′, NR″, O or S,
Y2 is CG1G2, SiG8G9, NG101, O or S,
y2 is 0 or 1, and when y2 is 0, Y2 is a direct bond,
A2 is a substituted or unsubstituted aromatic hydrocarbon ring; a substituted or unsubstituted aliphatic hydrocarbon ring; or a substituted or unsubstituted fused ring of an aromatic hydrocarbon ring and an aliphatic hydrocarbon ring,
Ar′1 is a substituted or unsubstituted cycloalkyl group; a substituted or unsubstituted aryl group; a substituted or unsubstituted fused ring group of an aromatic hydrocarbon ring and an aliphatic hydrocarbon ring; or a substituted or unsubstituted heterocyclic group,
R, R′ and R″ are the same as or different from each other, and each independently a substituted or unsubstituted alkyl group; a substituted or unsubstituted aryl group; or a substituted or unsubstituted heterocyclic group, or bond to each other to form a substituted or unsubstituted ring,
R′5 to R′8 are the same as or different from each other, and each independently hydrogen; deuterium; a halogen group; a cyano group; a substituted or unsubstituted alkyl group; a substituted or unsubstituted cycloalkyl group; a substituted or unsubstituted alkoxy group; a substituted or unsubstituted arylalkyl group; a substituted or unsubstituted aryloxy group; a substituted or unsubstituted silyl group; a substituted or unsubstituted amine group; a substituted or unsubstituted aryl group; a substituted or unsubstituted fused ring group of an aromatic hydrocarbon ring and an aliphatic hydrocarbon ring; or a substituted or unsubstituted heterocyclic group,
G1, G2, G7 to G12, G14, G15, G16 and G101 are the same as or different from each other, and each independently hydrogen; deuterium; a halogen group; a cyano group; a substituted or unsubstituted alkyl group; a substituted or unsubstituted cycloalkyl group; a substituted or unsubstituted alkoxy group; a substituted or unsubstituted arylalkyl group; a substituted or unsubstituted aryloxy group; a substituted or unsubstituted silyl group; a substituted or unsubstituted amine group; a substituted or unsubstituted aryl group; a substituted or unsubstituted fused ring group of an aromatic hydrocarbon ring and an aliphatic hydrocarbon ring; or a substituted or unsubstituted heterocyclic group, or adjacent groups bond to each other to form a substituted or unsubstituted aromatic hydrocarbon ring; a substituted or unsubstituted aliphatic hydrocarbon ring; or a substituted or unsubstituted fused ring of an aromatic hydrocarbon ring and an aliphatic hydrocarbon ring,
g7, g15 and g16 are each an integer of 1 to 4,
g10 is an integer of 1 to 8,
g14 is 1 or 2,
when g7, g10, g15 and g16 are each 2 or greater, substituents in the two or more parentheses are the same as or different from each other,
when g14 is 2, substituents in the two parentheses are the same as or different from each other,
Ar′1 and Ar′2 are the same as or different from each other, and each independently a substituted or unsubstituted cycloalkyl group; a substituted or unsubstituted aryl group; a substituted or unsubstituted fused ring group of an aromatic hydrocarbon ring and an aliphatic hydrocarbon ring; or a substituted or unsubstituted heterocyclic group, and
wherein in Chemical Formula 1-2-2,
when y2 is 1 and Y2 is O, G7 and R′6 to R′8 are hydrogen.

6. The compound of claim 1, wherein the compound of Chemical Formula 1 is represented by one of the following Chemical Formulae 1-3 to 1-5: 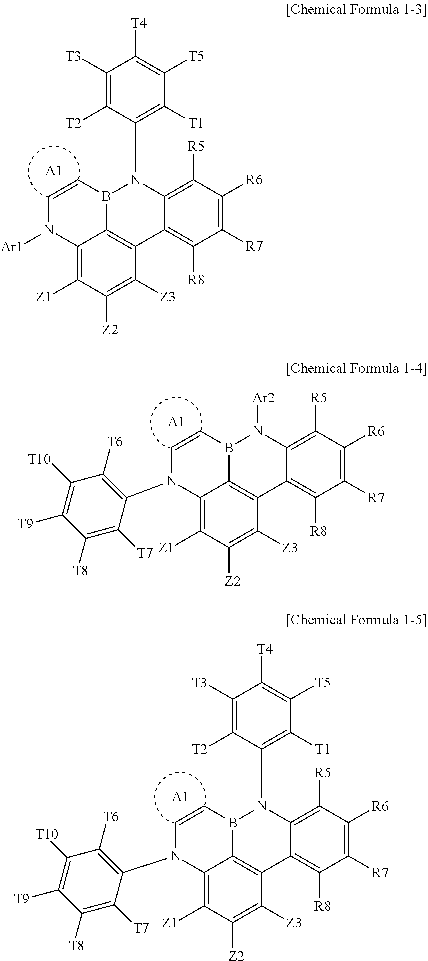
wherein in Chemical Formulae 1-3 to 1-5,
Ar1, Ar2, A1, R5 to R8 and Z1 to Z3 have the same definitions as in Chemical Formula
T1 to T10 are the same as or different from each other, and each independently hydrogen; deuterium; a halogen group; a cyano group; a substituted or unsubstituted alkyl group; a substituted or unsubstituted cycloalkyl group; a substituted or unsubstituted alkoxy group; a substituted or unsubstituted arylalkyl group; a substituted or unsubstituted aryloxy group; a substituted or unsubstituted silyl group; a substituted or unsubstituted amine group; a substituted or unsubstituted aryl group; a substituted or unsubstituted fused ring group of an aromatic hydrocarbon ring and an aliphatic hydrocarbon ring; or a substituted or unsubstituted heterocyclic group, or bond to adjacent groups to form a substituted or unsubstituted ring,
at least one of T1 and T2 is a substituted or unsubstituted alkyl group; a substituted or unsubstituted cycloalkyl group; a substituted or unsubstituted aryl group; a substituted or unsubstituted fused ring group of an aromatic hydrocarbon ring and an aliphatic hydrocarbon ring; or a substituted or unsubstituted heterocyclic group, and
at least one of T6 and T7 is a substituted or unsubstituted alkyl group; a substituted or unsubstituted cycloalkyl group; a substituted or unsubstituted aryl group; a substituted or unsubstituted fused ring group of an aromatic hydrocarbon ring and an aliphatic hydrocarbon ring; or a substituted or unsubstituted heterocyclic group.

7. The compound of claim 1, wherein adjacent groups among Z1 to Z3 bond to each other to form a ring represented by the following Chemical Formula C-1 or C-2: 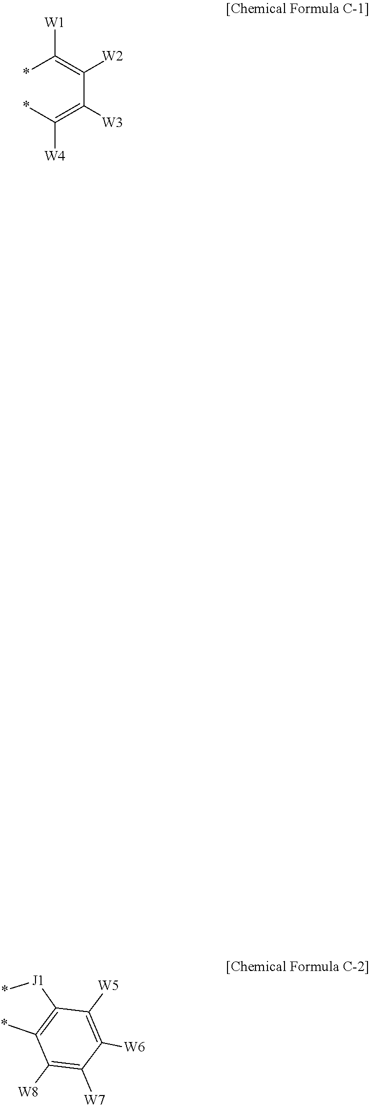
wherein in Chemical Formulae C-1 and C-2,
J1 is O, S, NQ7, CQ8Q9 or SiQ10Q11,
W1 to W8 and Q7 to Q11 are the same as or different from each other, and each independently hydrogen; deuterium; a halogen group; a cyano group; a substituted or unsubstituted alkyl group; a substituted or unsubstituted cycloalkyl group; a substituted or unsubstituted alkoxy group; a substituted or unsubstituted arylalkyl group; a substituted or unsubstituted aryloxy group; a substituted or unsubstituted silyl group; a substituted or unsubstituted amine group; a substituted or unsubstituted aryl group; a substituted or unsubstituted fused ring group of an aromatic hydrocarbon ring and an aliphatic hydrocarbon ring; or a substituted or unsubstituted heterocyclic group, or bond to adjacent groups to form a substituted or unsubstituted ring, and
* is a site bonding to Chemical Formula 1.

8. The compound of claim 1, wherein A1 is a monocyclic or polycyclic aromatic hydrocarbon ring having 6 to 30 carbon atoms unsubstituted or substituted with a linear or branched alkyl group having 1 to 30 carbon atoms, a fused ring group of a monocyclic or polycyclic aromatic hydrocarbon ring having 6 to 30 carbon atoms and a monocyclic or polycyclic aliphatic hydrocarbon ring having 3 to 30 carbon atoms unsubstituted or substituted with a linear or branched alkyl group having 1 to 30 carbon atoms, a monocyclic or polycyclic aryl group having 6 to 30 carbon atoms, or NQ1Q2; a fused ring of a monocyclic or polycyclic aromatic hydrocarbon ring having 6 to 30 carbon atoms and a monocyclic or polycyclic aliphatic hydrocarbon ring having 3 to 30 carbon atoms unsubstituted or substituted with a linear or branched alkyl group having 1 to 30 carbon atoms; or a monocyclic or polycyclic heteroring having 2 to 30 carbon atoms unsubstituted or substituted with a linear or branched alkyl group having 1 to 30 carbon atoms or a monocyclic or polycyclic aryl group having 6 to 30 carbon atoms,
Q1 and Q2 are the same as or different from each other, and each independently a monocyclic or polycyclic aryl group having 6 to 30 carbon atoms unsubstituted or substituted with a linear or branched alkyl group having 1 to 30 carbon atoms; a fused ring group of a monocyclic or polycyclic aromatic hydrocarbon ring having 6 to 30 carbon atoms and a monocyclic or polycyclic aliphatic hydrocarbon ring having 3 to 30 carbon atoms unsubstituted or substituted with a linear or branched alkyl group having 1 to 30 carbon atoms; or a monocyclic or polycyclic heterocyclic group having 2 to 30 carbon atoms,
R5 to R8 are the same as or different from each other, and each independently hydrogen; deuterium; a linear or branched alkyl group having 1 to 30 carbon atoms; a monocyclic or polycyclic aryl group having 6 to 30 carbon atoms; or NQ3Q4, or bond to adjacent groups to form a monocyclic or polycyclic aliphatic hydrocarbon ring having 3 to 30 carbon atoms unsubstituted or substituted with a linear or branched alkyl group having 1 to 30 carbon atoms; a monocyclic or polycyclic aromatic hydrocarbon ring having 6 to 30 carbon atoms unsubstituted or substituted with a linear or branched alkyl group having 1 to 30 carbon atoms, or a monocyclic or polycyclic diarylamine group having 6 to 30 carbon atoms unsubstituted or substituted with a linear or branched alkyl group having 1 to 30 carbon atoms; a fused ring of a monocyclic or polycyclic aromatic hydrocarbon ring having 6 to 30 carbon atoms and a monocyclic or polycyclic aliphatic hydrocarbon ring having 3 to 30 carbon atoms unsubstituted or substituted with a linear or branched alkyl group having 1 to 30 carbon atoms; or a monocyclic or polycyclic heteroring having 2 to 30 carbon atoms unsubstituted or substituted with a linear or branched alkyl group having 1 to 30 carbon atoms, a monocyclic or polycyclic aryl group having 6 to 30 carbon atoms, or a monocyclic or polycyclic diarylamine group having 6 to 30 carbon atoms unsubstituted or substituted with a linear or branched alkyl group having 1 to 30 carbon atoms;
Q3 and Q4 are the same as or different from each other, and each independently a monocyclic or polycyclic aryl group having 6 to 30 carbon atoms unsubstituted or substituted with a linear or branched alkyl group having 1 to 30 carbon atoms; a fused ring group of a monocyclic or polycyclic aromatic hydrocarbon ring having 6 to 30 carbon atoms and a monocyclic or polycyclic aliphatic hydrocarbon ring having 3 to 30 carbon atoms unsubstituted or substituted with a linear or branched alkyl group having 1 to 30 carbon atoms; or a monocyclic or polycyclic heterocyclic group having 2 to 30 carbon atoms;
Ar1 is a monocyclic or polycyclic aryl group having 6 to 30 carbon atoms unsubstituted or substituted with one or more selected from the group consisting of a linear or branched alkyl group having 1 to 30 carbon atoms, a monocyclic or polycyclic aryl group having 6 to 30 carbon atoms, and a combination thereof; a fused ring group of a monocyclic or polycyclic aromatic hydrocarbon ring having 6 to 30 carbon atoms and a monocyclic or polycyclic aliphatic hydrocarbon ring having 3 to 30 carbon atoms unsubstituted or substituted with a linear or branched alkyl group having 1 to 30 carbon atoms; or a monocyclic or polycyclic heterocyclic group having 2 to 30 carbon atoms, or bonds to A1 to form one selected from the group consisting of a monocyclic or polycyclic aromatic heteroring having 2 to 30 carbon atoms, a monocyclic or polycyclic aliphatic heteroring having 2 to 30 carbon atoms, and a fused ring thereof, each of which is unsubstituted or substituted with a linear or branched alkyl group having 1 to 30 carbon atoms, a monocyclic or polycyclic cycloalkyl group having 3 to 30 carbon atoms, or a monocyclic or polycyclic aryl group having 6 to 30 carbon atoms and includes one or more selected from N, S, O and Si,
Ar2 is a monocyclic or polycyclic aryl group having 6 to 30 carbon atoms unsubstituted or substituted with one or more selected from the group consisting of a linear or branched alkyl group having 1 to 30 carbon atoms, a monocyclic or polycyclic aryl group having 6 to 30 carbon atoms, and a combination thereof; a fused ring group of a monocyclic or polycyclic aromatic hydrocarbon ring having 6 to 30 carbon atoms and a monocyclic or polycyclic aliphatic hydrocarbon ring having 3 to 30 carbon atoms unsubstituted or substituted with a linear or branched alkyl group having 1 to 30 carbon atoms; or a monocyclic or polycyclic heterocyclic group having 2 to 30 carbon atoms, or bonds to R5 to form one selected from the group consisting of a monocyclic or polycyclic aromatic heteroring having 2 to 30 carbon atoms, a monocyclic or polycyclic aliphatic heteroring having 2 to 30 carbon atoms, and a fused ring thereof unsubstituted or substituted with a linear or branched alkyl group having 1 to 30 carbon atoms, a monocyclic or polycyclic cycloalkyl group having 3 to 30 carbon atoms or a monocyclic or polycyclic aryl group having 6 to 30 carbon atoms and including one or more selected from N, S, O and Si,
at least one of Z1 to Z3 is deuterium; a linear or branched alkyl group having 1 to 30 carbon atoms; a monocyclic or polycyclic cycloalkyl group having 3 to 30 carbon atoms; a monocyclic or polycyclic aryl group having 6 to 30 carbon atoms unsubstituted or substituted with deuterium, or a linear or branched alkyl group having 1 to 30 carbon atoms; or NQ5Q6, or bonds to adjacent groups to form a monocyclic or polycyclic aromatic hydrocarbon ring having 6 to 30 carbon atoms unsubstituted or substituted with a linear or branched alkyl group having 1 to 30 carbon atoms; or a monocyclic or polycyclic heteroring having 2 to 30 carbon atoms unsubstituted or substituted with one or more substituents selected from among a linear or branched alkyl group having 1 to 30 carbon atoms, a monocyclic or polycyclic aryl group having 6 to 30 carbon atoms, a fused ring group of an aromatic hydrocarbon ring and an aliphatic hydrocarbon ring, and a combination thereof, and the rest are hydrogen,
Q5 and Q6 are the same as or different from each other, and each independently a monocyclic or polycyclic aryl group having 6 to 30 carbon atoms unsubstituted or substituted with a linear or branched alkyl group having 1 to 30 carbon atoms; a fused ring group of a monocyclic or polycyclic aromatic hydrocarbon ring having 6 to 30 carbon atoms and a monocyclic or polycyclic aliphatic hydrocarbon ring having 3 to 30 carbon atoms unsubstituted or substituted with a linear or branched alkyl group having 1 to 30 carbon atoms; or a monocyclic or polycyclic heterocyclic group having 2 to 30 carbon atoms,
when Ar2 and R5 form a benzoxazine ring, the benzoxazine ring is an unsubstituted benzoxazine ring, and
when Ar1 is a phenyl group, and A1 is substituted or unsubstituted benzene, and R6 to R8 are hydrogen, and adjacent groups among Z1 to Z3 do not bond to each other to form a substituted or unsubstituted ring, and Ar2 and R5 form an indole group at the same time, the indole group is a substituted indole group.

9. The compound of claim 1, wherein the compound of Chemical Formula 1 one selected from the following compounds: 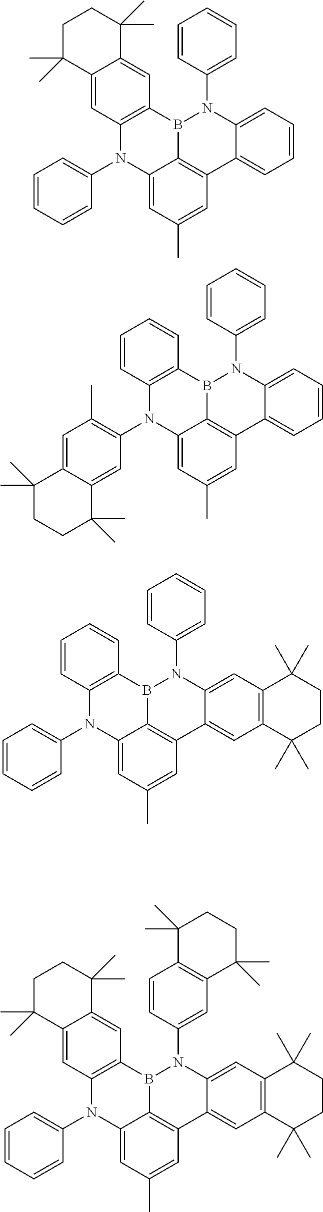 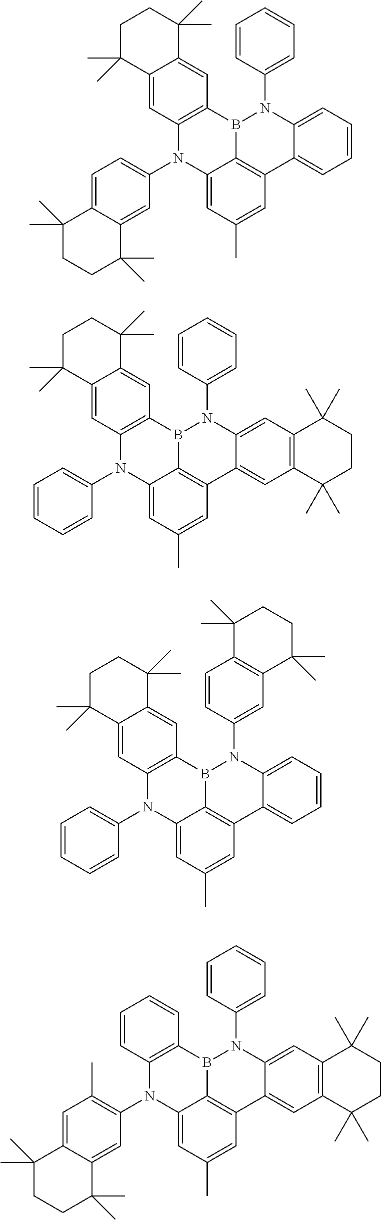 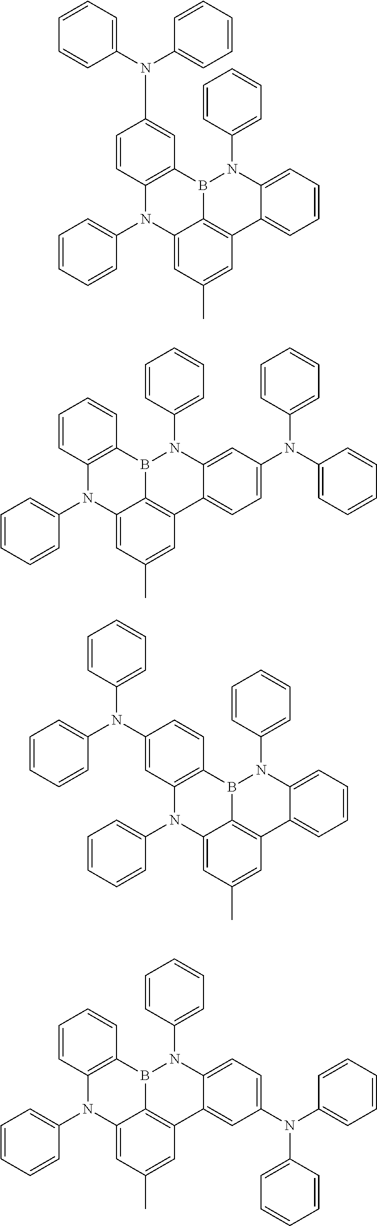 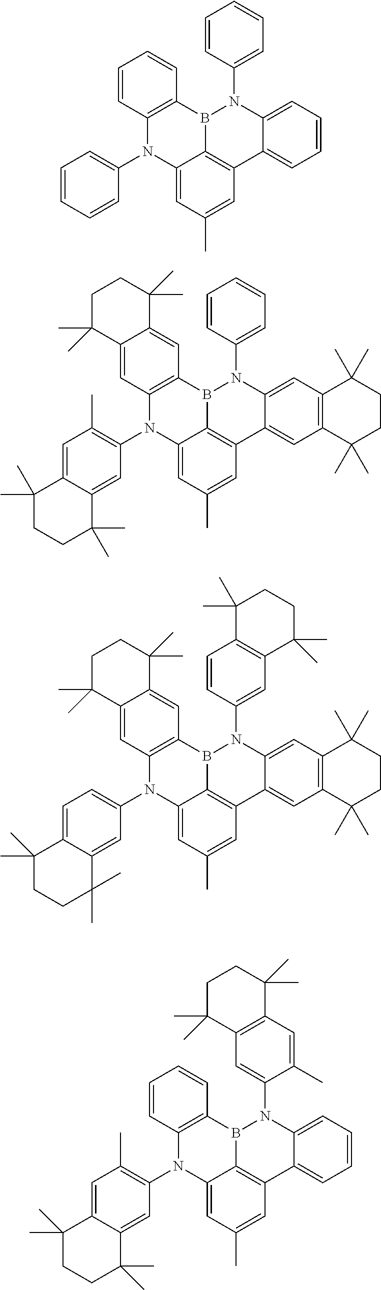 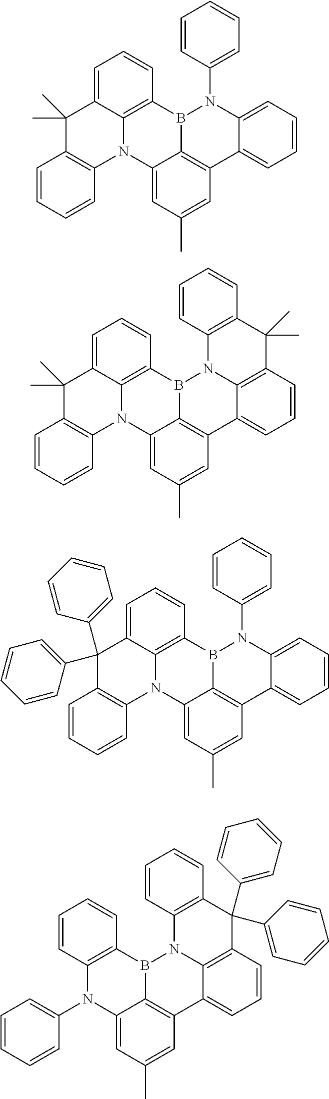 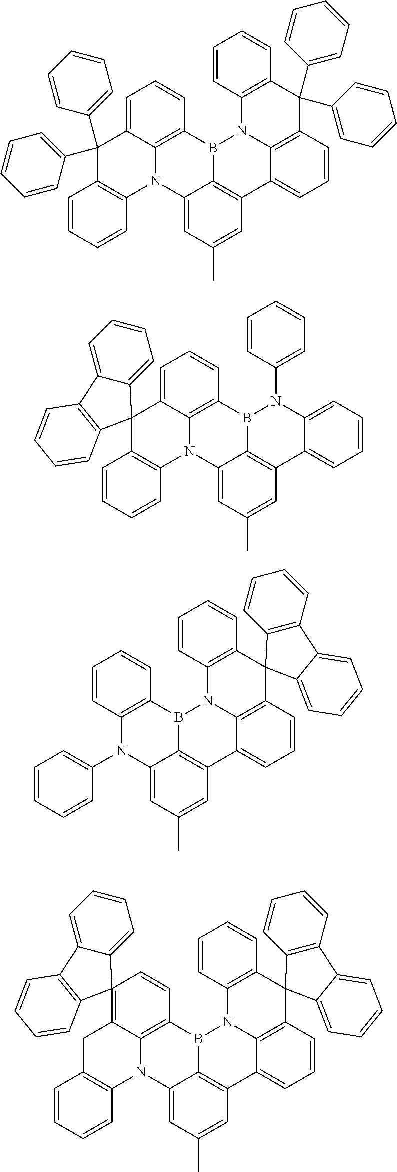 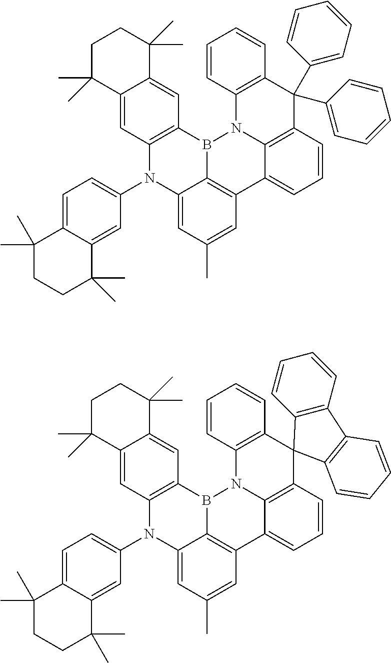 [SMILES: Cc1cc2c3c(c1)N(c1ccc4c(c1)C(C)(C)CCC4(C)C)c1cc4c(cc1B3N1c3ccccc3C(c3ccccc3)(c3ccccc3)c3cccc-2c31)C(C)(C)CCC4(C)C ; Cc1cc2c3c(c1)N(c1ccc4c(c1)C(C)(C)CCC4(C)C)c1cc4c(cc1B3N1c3ccccc3C3(c5ccccc5-c5ccccc53)c3cccc-2c31)C(C)(C)CCC4(C)C] 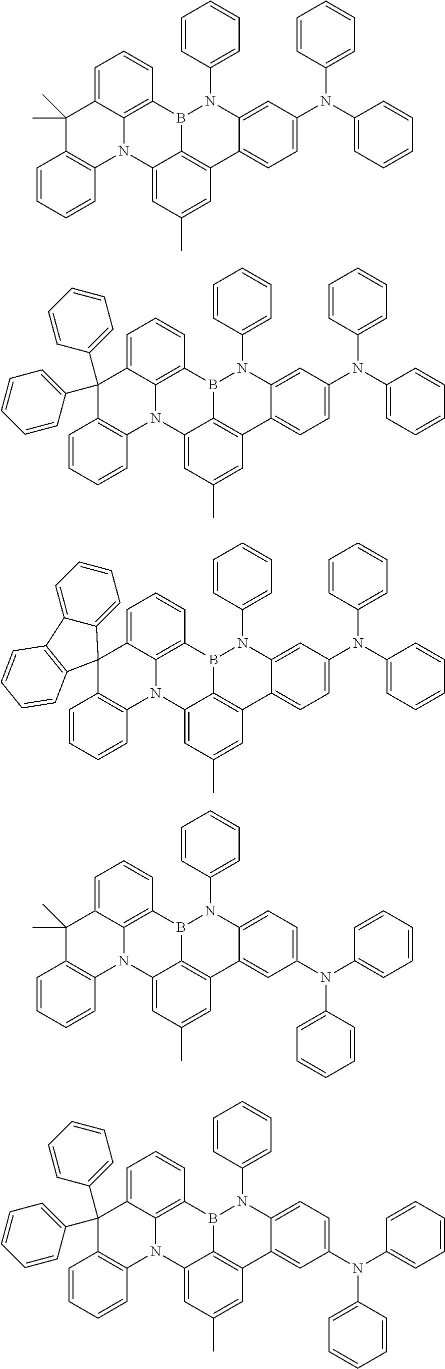 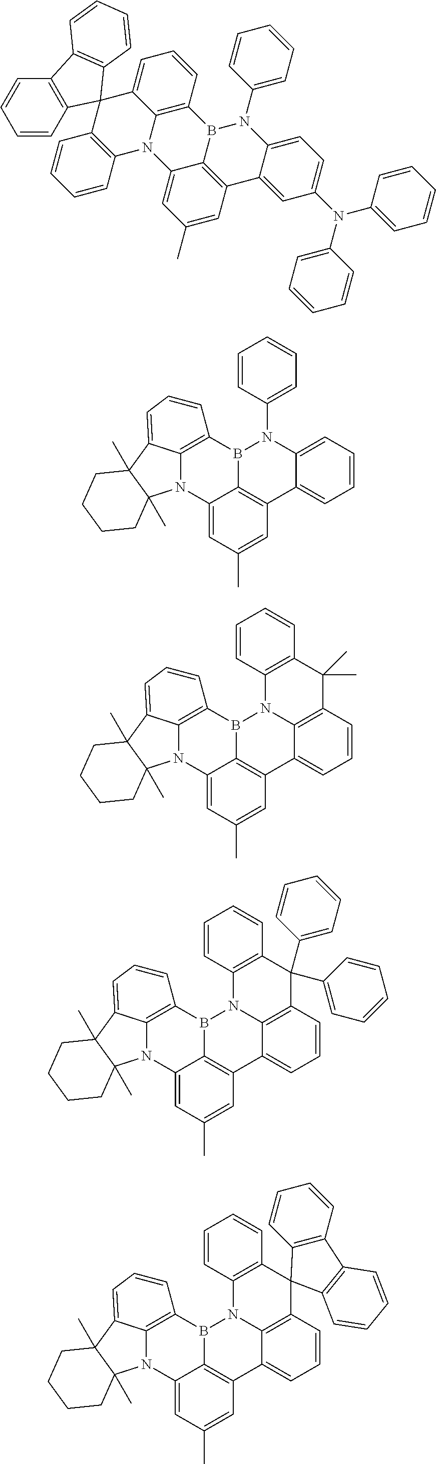 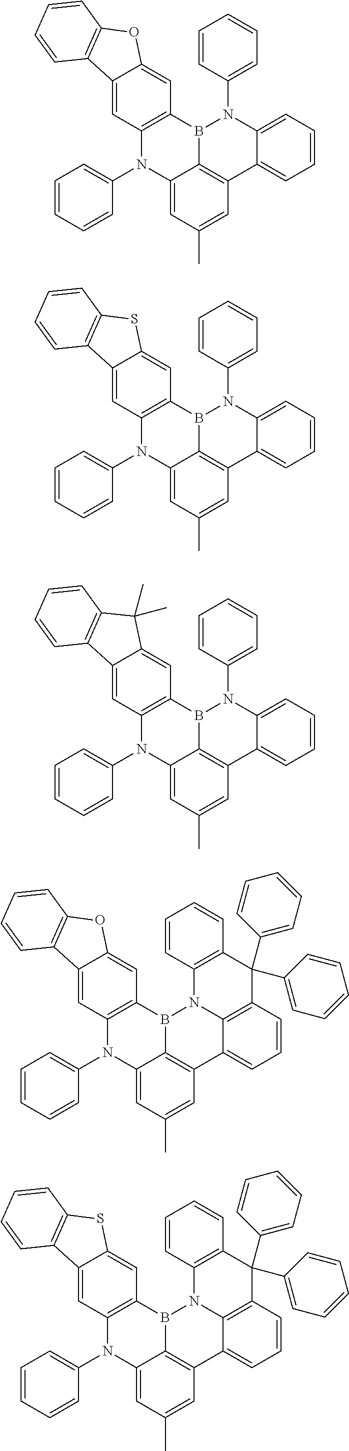 [SMILES: Cc1cc2c3c(c1)N(c1ccccc1)c1cc4c(cc1B3N(c1ccccc1)c1ccccc1-2)oc1ccccc14 ; Cc1cc2c3c(c1)N(c1ccccc1)c1cc4c(cc1B3N(c1ccccc1)c1ccccc1-2)sc1ccccc14 ; Cc1cc2c3c(c1)N(c1ccccc1)c1cc4c(cc1B3N(c1ccccc1)c1ccccc1-2)C(C)(C)c1ccccc1-4 ; Cc1cc2c3c(c1)N(c1ccccc1)c1cc4c(cc1B3N1c3ccccc3C(c3ccccc3)(c3ccccc3)c3cccc-2c31)oc1ccccc14 ; Cc1cc2c3c(c1)N(c1ccccc1)c1cc4c(cc1B3N1c3ccccc3C(c3ccccc3)(c3ccccc3)c3cccc-2c31)sc1ccccc14] 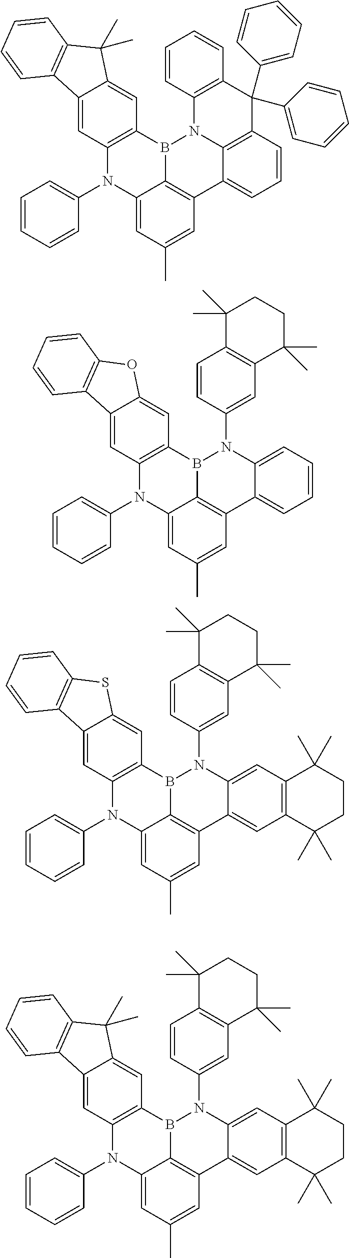 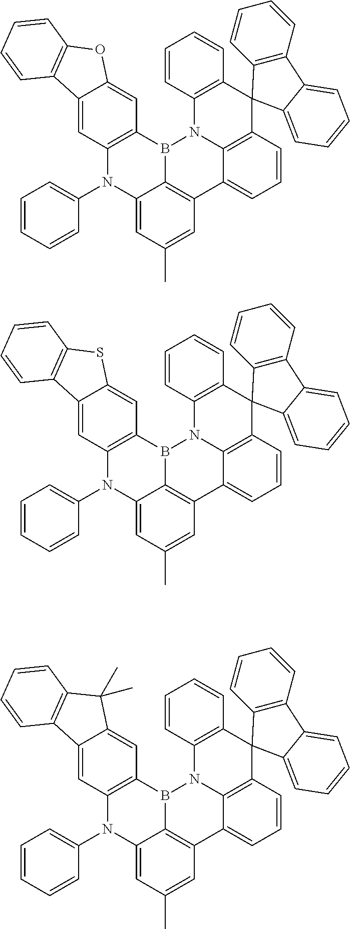 [SMILES: Cc1cc2c3c(c1)N(c1ccccc1)c1cc4c(cc1B3N1c3ccccc3C3(c5ccccc5-c5ccccc53)c3cccc-2c31)oc1ccccc14 ; Cc1cc2c3c(c1)N(c1ccccc1)c1cc4c(cc1B3N1c3ccccc3C3(c5ccccc5-c5ccccc53)c3cccc-2c31)sc1ccccc14 ; Cc1cc2c3c(c1)N(c1ccccc1)c1cc4c(cc1B3N1c3ccccc3C3(c5ccccc5-c5ccccc53)c3cccc-2c31)C(C)(C)c1ccccc1-4] 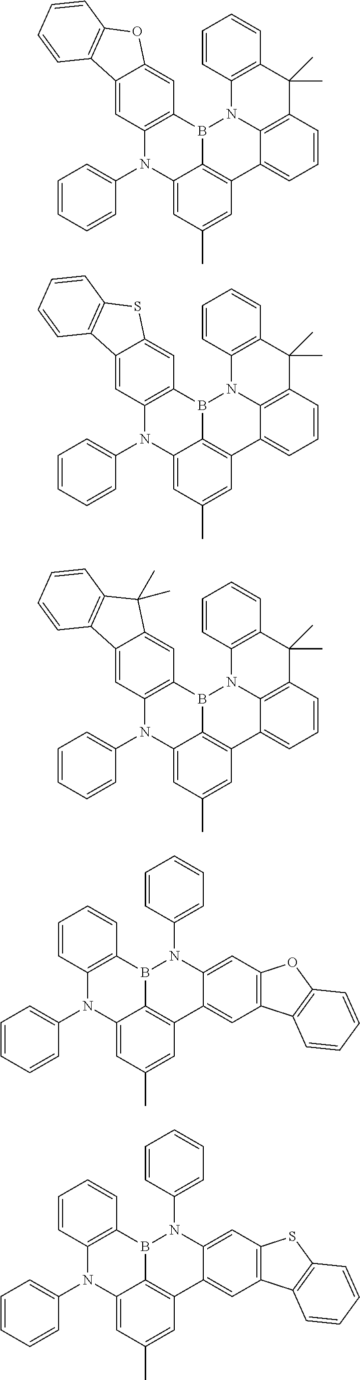 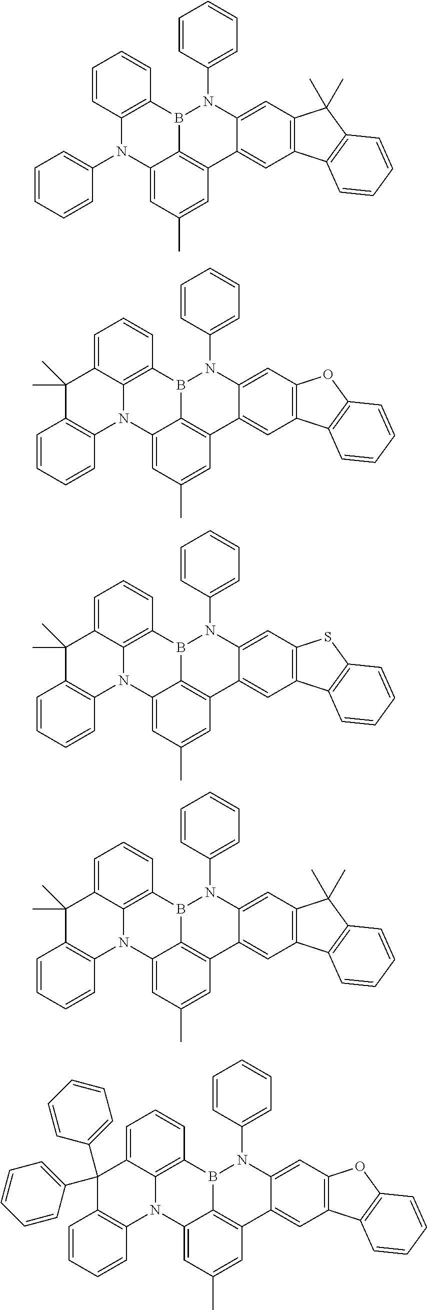 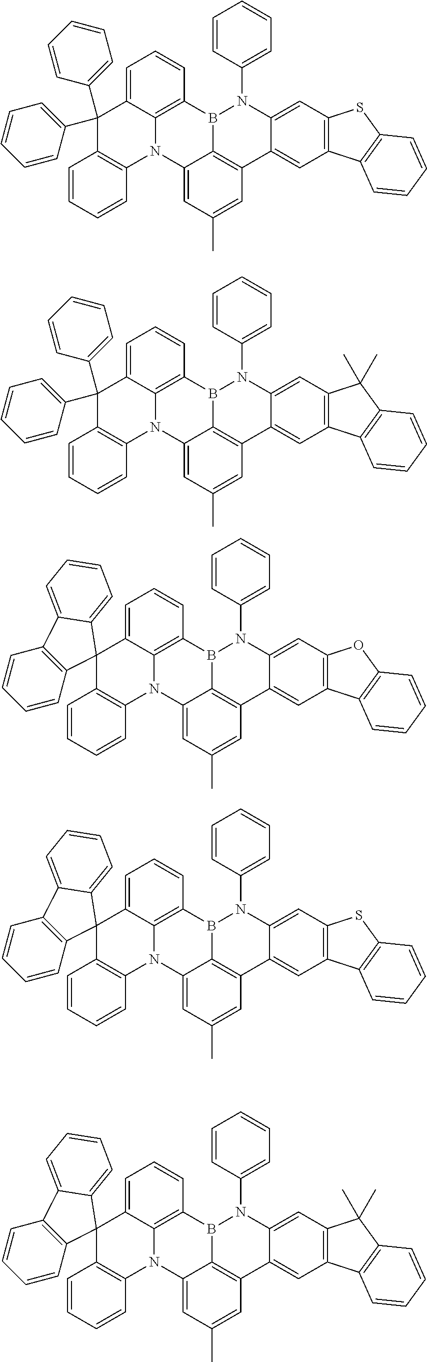 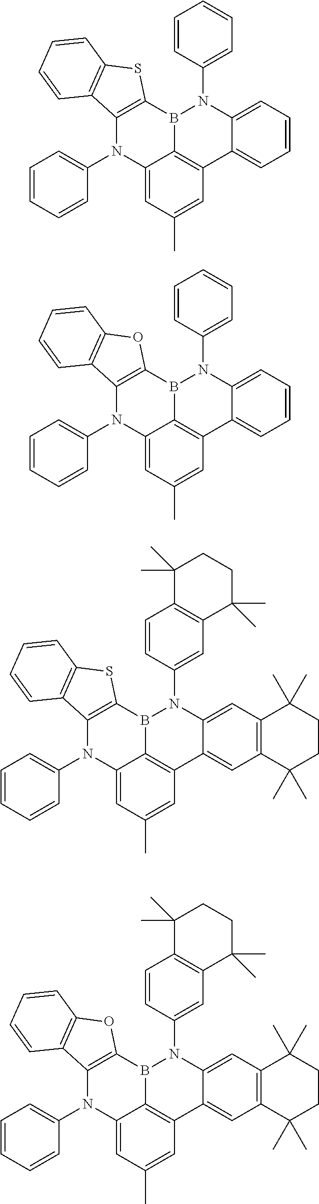 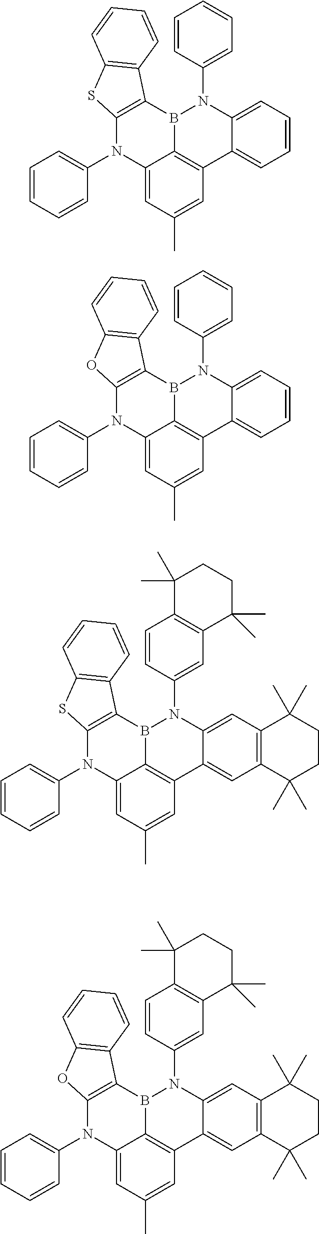 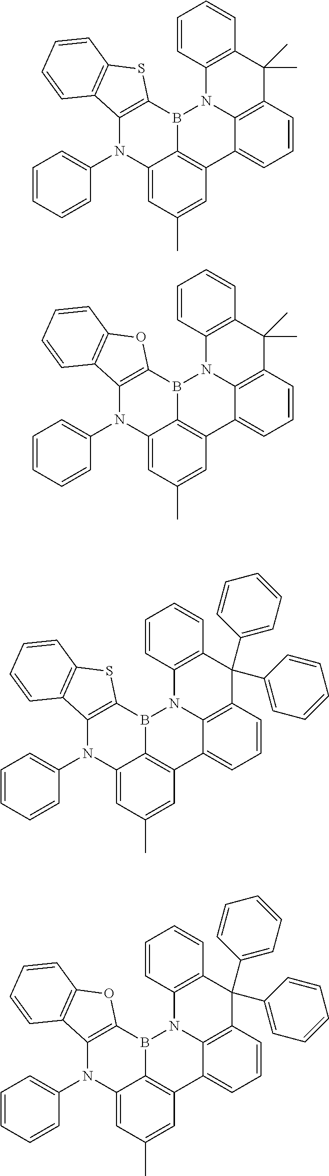 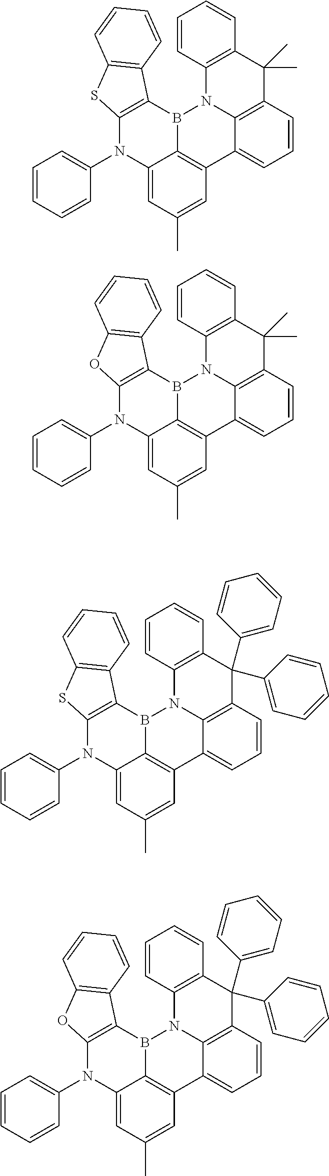 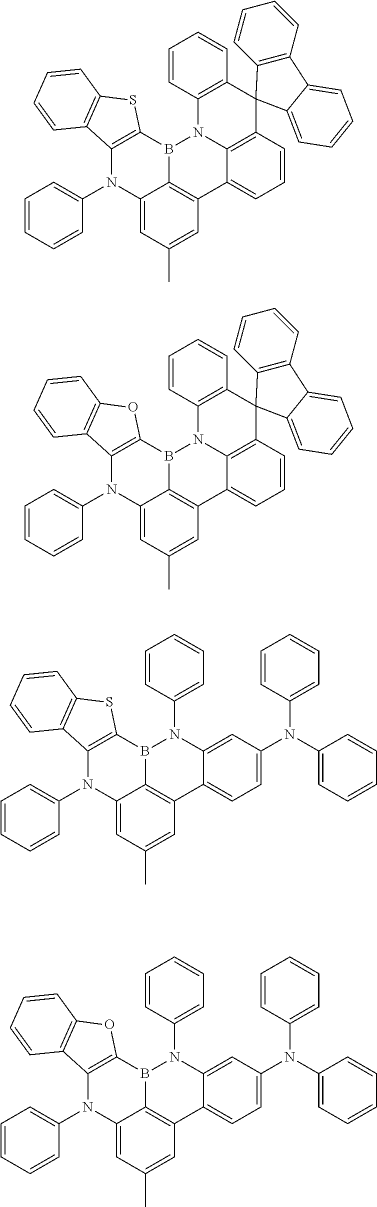 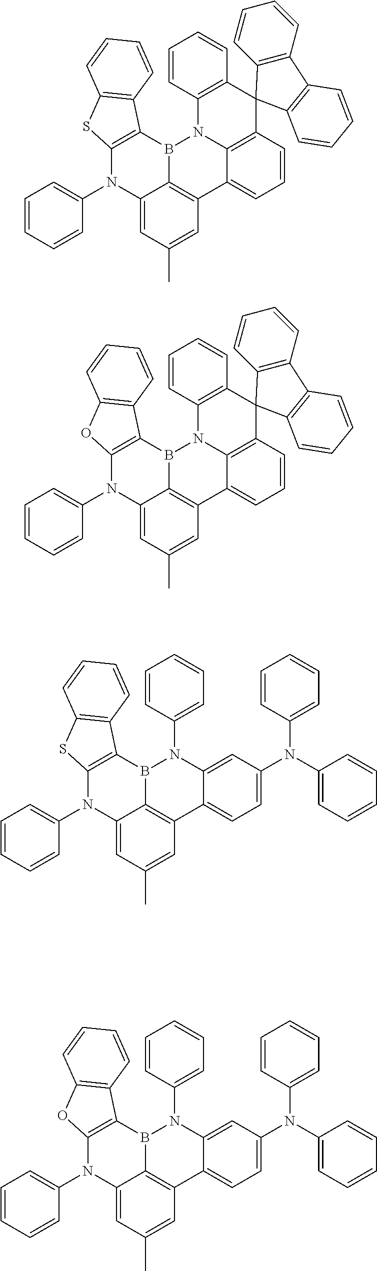 [SMILES: Cc1cc2c3c(c1)N(c1ccccc1)c1sc4ccccc4c1B3N1c3ccccc3C3(c4ccccc4-c4ccccc43)c3cccc-2c31 ; Cc1cc2c3c(c1)N(c1ccccc1)c1oc4ccccc4c1B3N1c3ccccc3C3(c4ccccc4-c4ccccc43)c3cccc-2c31 ; Cc1cc2c3c(c1)N(c1ccccc1)c1sc4ccccc4c1B3N(c1ccccc1)c1cc(N(c3ccccc3)c3ccccc3)ccc1-2 ; Cc1cc2c3c(c1)N(c1ccccc1)c1oc4ccccc4c1B3N(c1ccccc1)c1cc(N(c3ccccc3)c3ccccc3)ccc1-2] 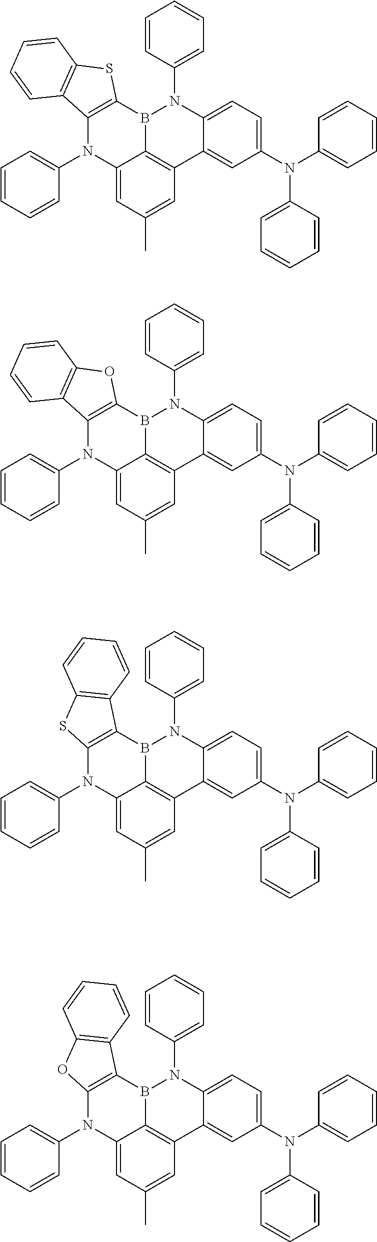 [SMILES: Cc1cc2c3c(c1)N(c1ccccc1)c1c(sc4ccccc14)B3N(c1ccccc1)c1ccc(N(c3ccccc3)c3ccccc3)cc1-2 ; Cc1cc2c3c(c1)N(c1ccccc1)c1c(oc4ccccc14)B3N(c1ccccc1)c1ccc(N(c3ccccc3)c3ccccc3)cc1-2 ; Cc1cc2c3c(c1)N(c1ccccc1)c1sc4ccccc4c1B3N(c1ccccc1)c1ccc(N(c3ccccc3)c3ccccc3)cc1-2 ; Cc1cc2c3c(c1)N(c1ccccc1)c1oc4ccccc4c1B3N(c1ccccc1)c1ccc(N(c3ccccc3)c3ccccc3)cc1-2] 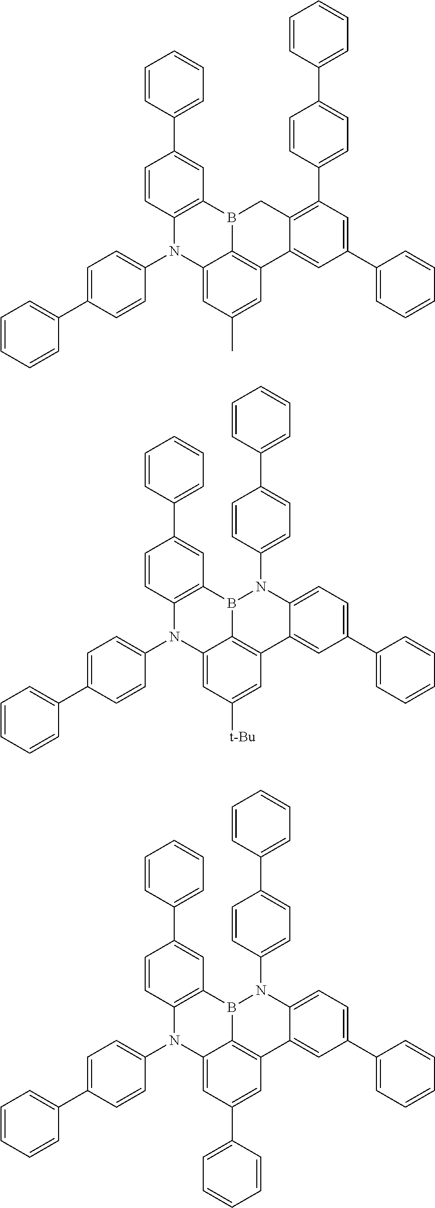 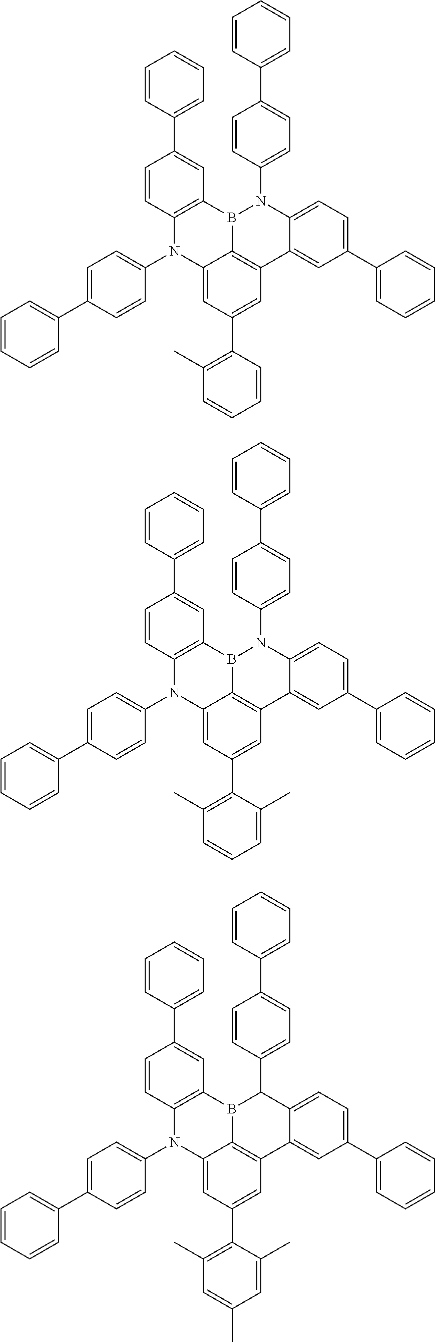 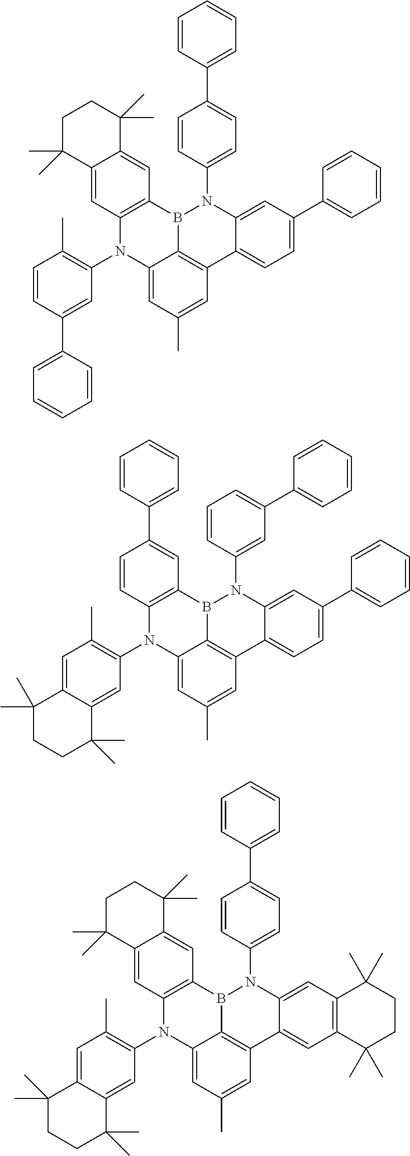 [SMILES: Cc1cc2c3c(c1)N(c1cc(-c4ccccc4)ccc1C)c1cc4c(cc1B3N(c1ccc(-c3ccccc3)cc1)c1cc(-c3ccccc3)ccc1-2)C(C)(C)CCC4(C)C ; Cc1cc2c3c(c1)N(c1cc4c(cc1C)C(C)(C)CCC4(C)C)c1ccc(-c4ccccc4)cc1B3N(c1cccc(-c3ccccc3)c1)c1cc(-c3ccccc3)ccc1-2 ; Cc1cc2c3c(c1)N(c1cc4c(cc1C)C(C)(C)CCC4(C)C)c1cc4c(cc1B3N(c1ccc(-c3ccccc3)cc1)c1cc3c(cc1-2)C(C)(C)CCC3(C)C)C(C)(C)CCC4(C)C] 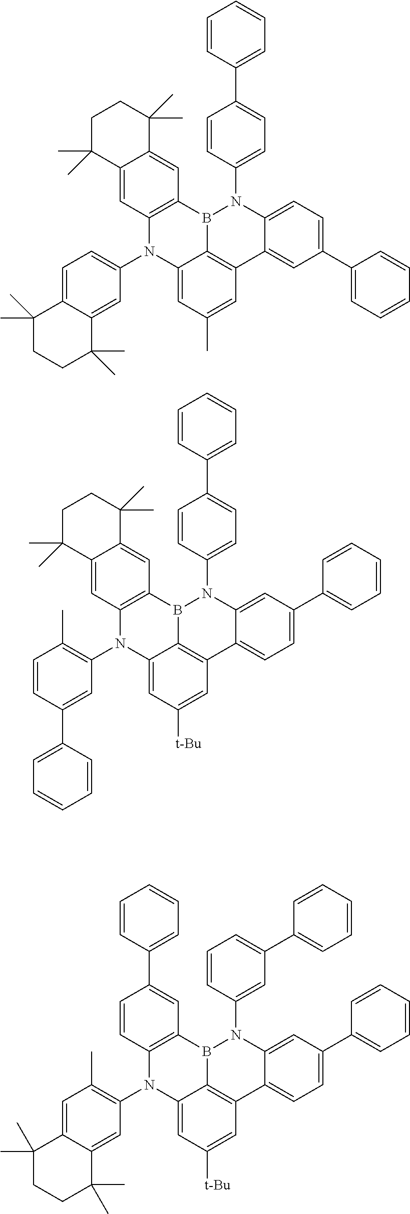 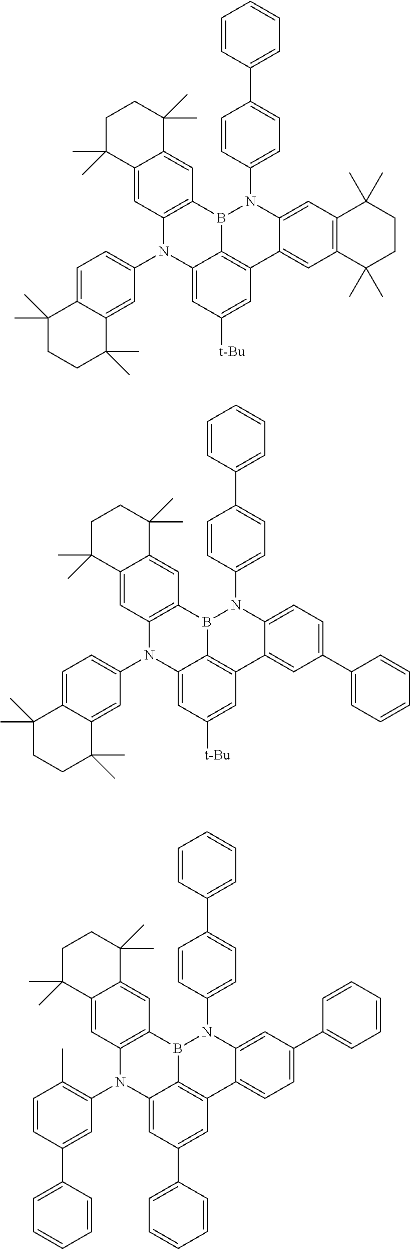 [SMILES: CC(C)(C)c1cc2c3c(c1)N(c1ccc4c(c1)C(C)(C)CCC4(C)C)c1cc4c(cc1B3N(c1ccc(-c3ccccc3)cc1)c1cc3c(cc1-2)C(C)(C)CCC3(C)C)C(C)(C)CCC4(C)C ; CC(C)(C)c1cc2c3c(c1)N(c1ccc4c(c1)C(C)(C)CCC4(C)C)c1cc4c(cc1B3N(c1ccc(-c3ccccc3)cc1)c1ccc(-c3ccccc3)cc1-2)C(C)(C)CCC4(C)C ; Cc1ccc(-c2ccccc2)cc1N1c2cc3c(cc2B2c4c(cc(-c5ccccc5)cc41)-c1ccc(-c4ccccc4)cc1N2c1ccc(-c2ccccc2)cc1)C(C)(C)CCC3(C)C] 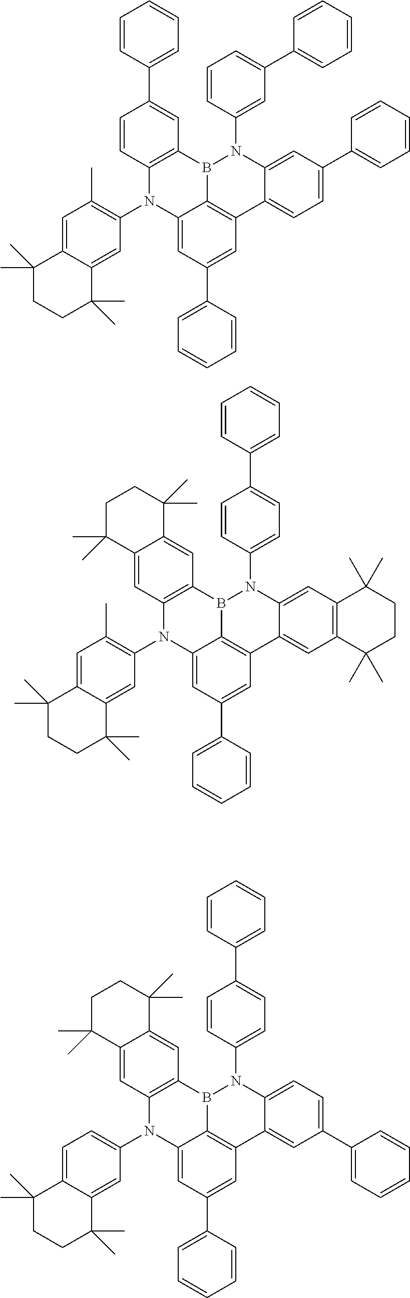 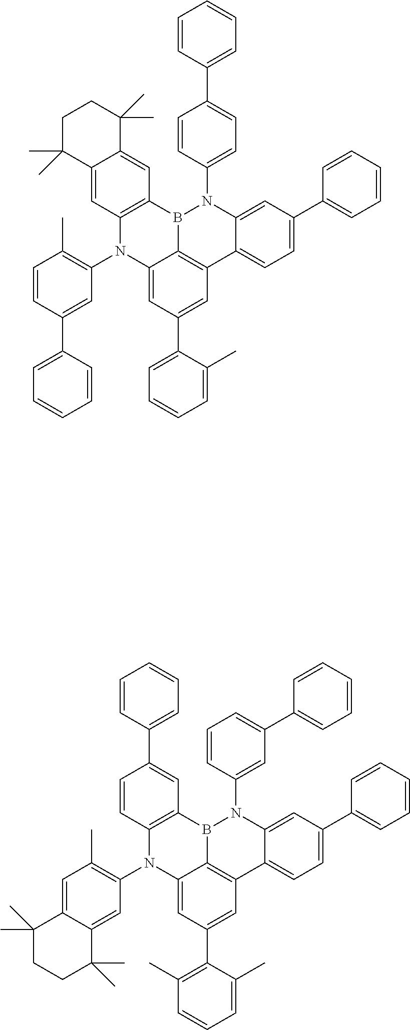 [SMILES: Cc1ccccc1-c1cc2c3c(c1)N(c1cc(-c4ccccc4)ccc1C)c1cc4c(cc1B3N(c1ccc(-c3ccccc3)cc1)c1cc(-c3ccccc3)ccc1-2)C(C)(C)CCC4(C)C ; Cc1cc2c(cc1N1c3ccc(-c4ccccc4)cc3B3c4c(cc(-c5c(C)cccc5C)cc41)-c1ccc(-c4ccccc4)cc1N3c1cccc(-c3ccccc3)c1)C(C)(C)CCC2(C)C] 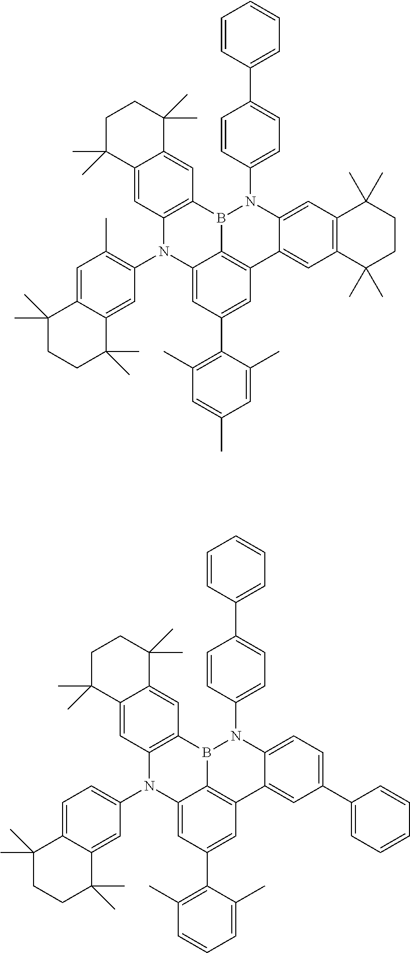 [SMILES: Cc1cc(C)c(-c2cc3c4c(c2)N(c2cc5c(cc2C)C(C)(C)CCC5(C)C)c2cc5c(cc2B4N(c2ccc(-c4ccccc4)cc2)c2cc4c(cc2-3)C(C)(C)CCC4(C)C)C(C)(C)CCC5(C)C)c(C)c1 ; Cc1cccc(C)c1-c1cc2c3c(c1)N(c1ccc4c(c1)C(C)(C)CCC4(C)C)c1cc4c(cc1B3N(c1ccc(-c3ccccc3)cc1)c1ccc(-c3ccccc3)cc1-2)C(C)(C)CCC4(C)C] 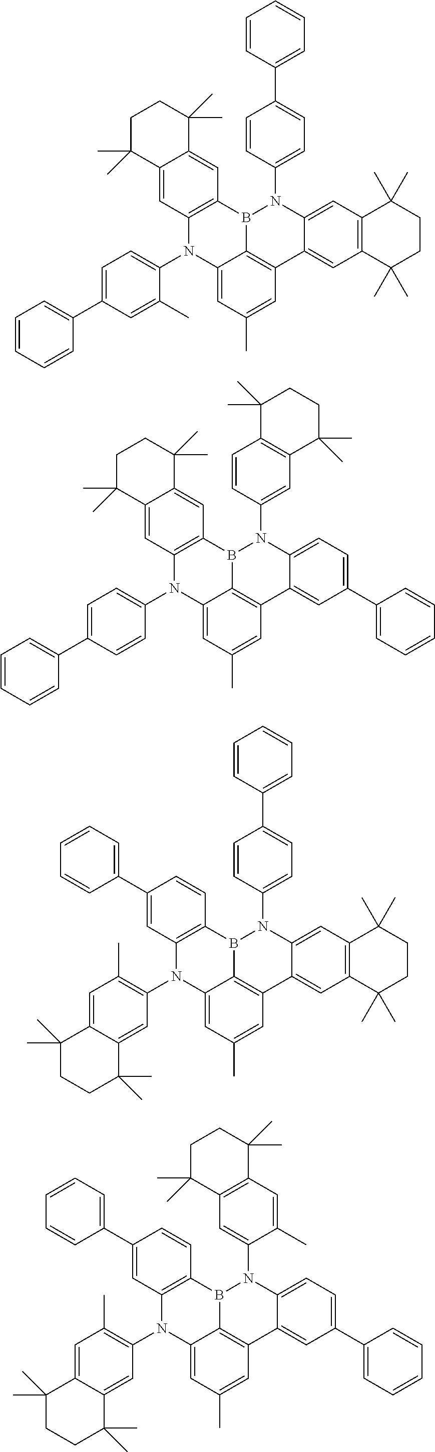 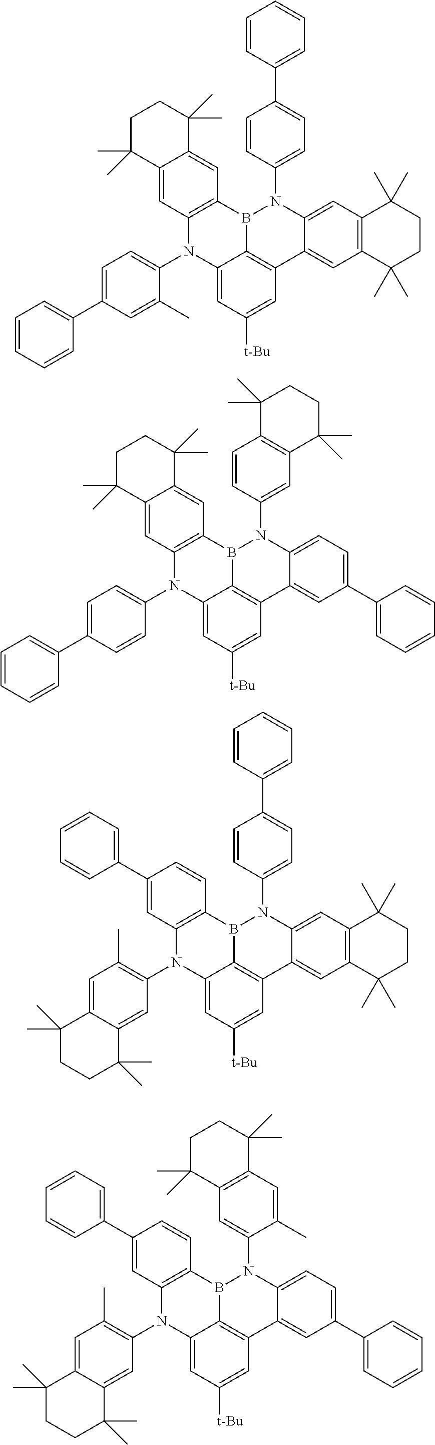 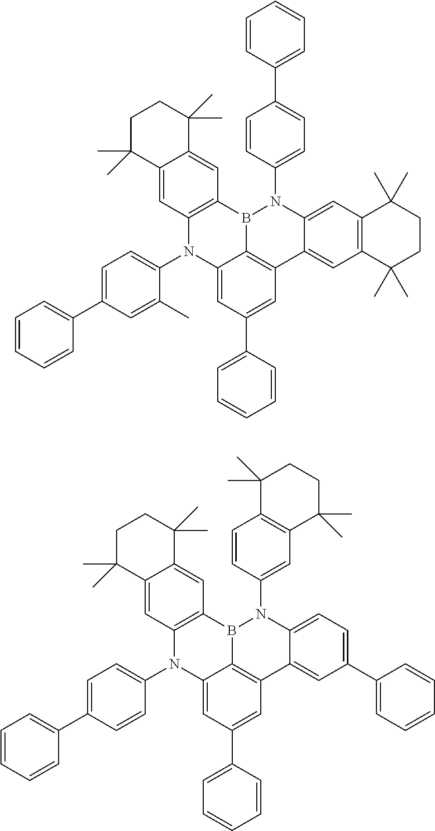 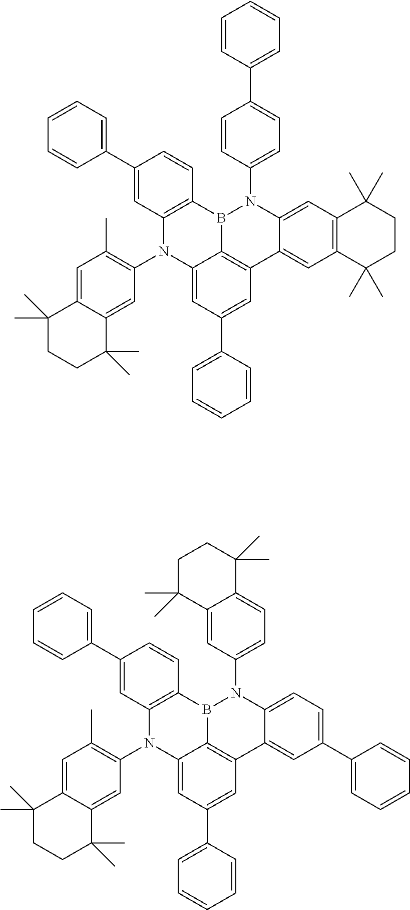 [SMILES: Cc1cc2c(cc1N1c3cc(-c4ccccc4)ccc3B3c4c(cc(-c5ccccc5)cc41)-c1cc4c(cc1N3c1ccc(-c3ccccc3)cc1)C(C)(C)CCC4(C)C)C(C)(C)CCC2(C)C ; Cc1cc2c(cc1N1c3cc(-c4ccccc4)ccc3B3c4c(cc(-c5ccccc5)cc41)-c1cc(-c4ccccc4)ccc1N3c1ccc3c(c1)C(C)(C)CCC3(C)C)C(C)(C)CCC2(C)C] 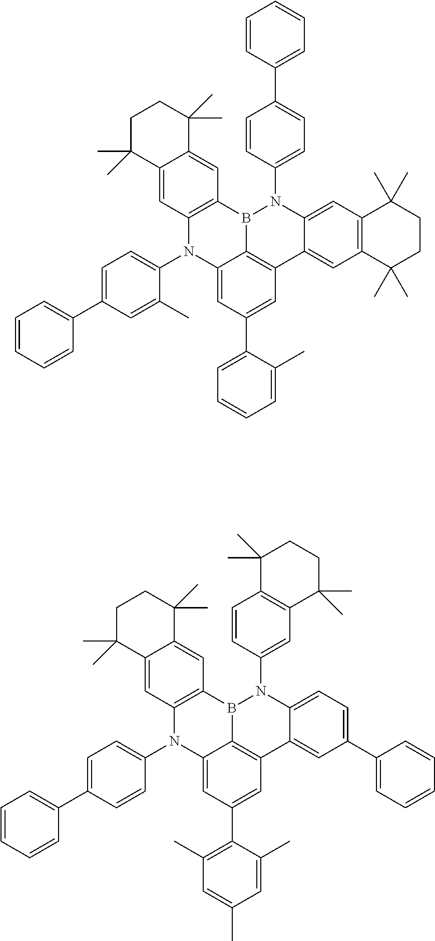 [SMILES: Cc1ccccc1-c1cc2c3c(c1)N(c1ccc(-c4ccccc4)cc1C)c1cc4c(cc1B3N(c1ccc(-c3ccccc3)cc1)c1cc3c(cc1-2)C(C)(C)CCC3(C)C)C(C)(C)CCC4(C)C ; Cc1cc(C)c(-c2cc3c4c(c2)N(c2ccc(-c5ccccc5)cc2)c2cc5c(cc2B4N(c2ccc4c(c2)C(C)(C)CCC4(C)C)c2ccc(-c4ccccc4)cc2-3)C(C)(C)CCC5(C)C)c(C)c1] 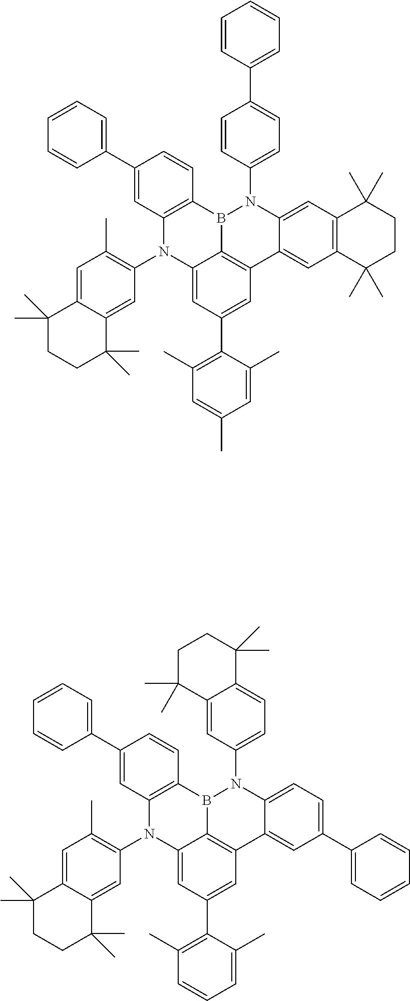 [SMILES: Cc1cc(C)c(-c2cc3c4c(c2)N(c2cc5c(cc2C)C(C)(C)CCC5(C)C)c2cc(-c5ccccc5)ccc2B4N(c2ccc(-c4ccccc4)cc2)c2cc4c(cc2-3)C(C)(C)CCC4(C)C)c(C)c1 ; Cc1cc2c(cc1N1c3cc(-c4ccccc4)ccc3B3c4c(cc(-c5c(C)cccc5C)cc41)-c1cc(-c4ccccc4)ccc1N3c1ccc3c(c1)C(C)(C)CCC3(C)C)C(C)(C)CCC2(C)C] 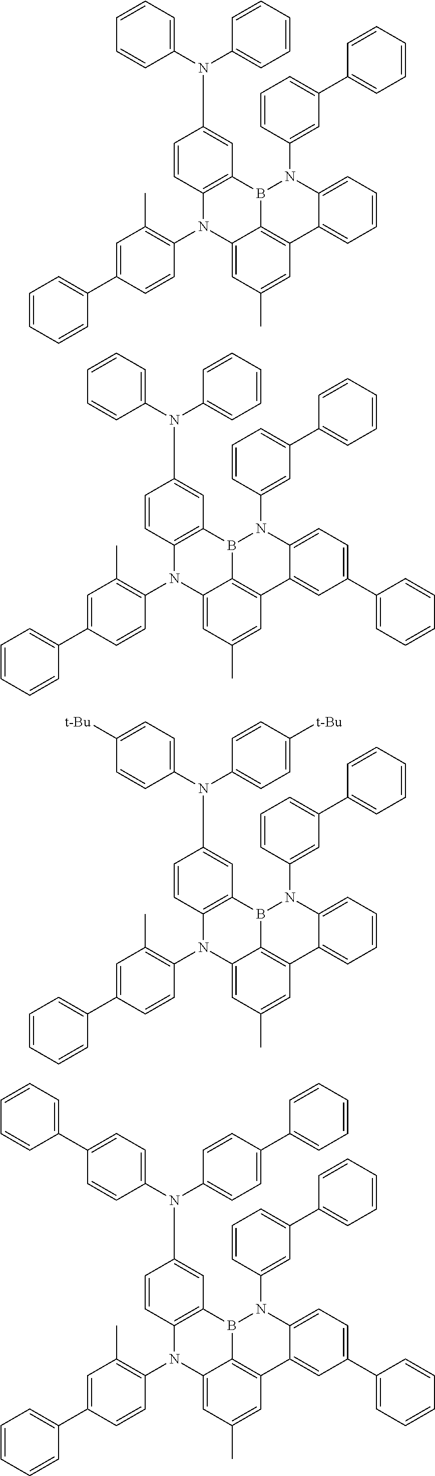 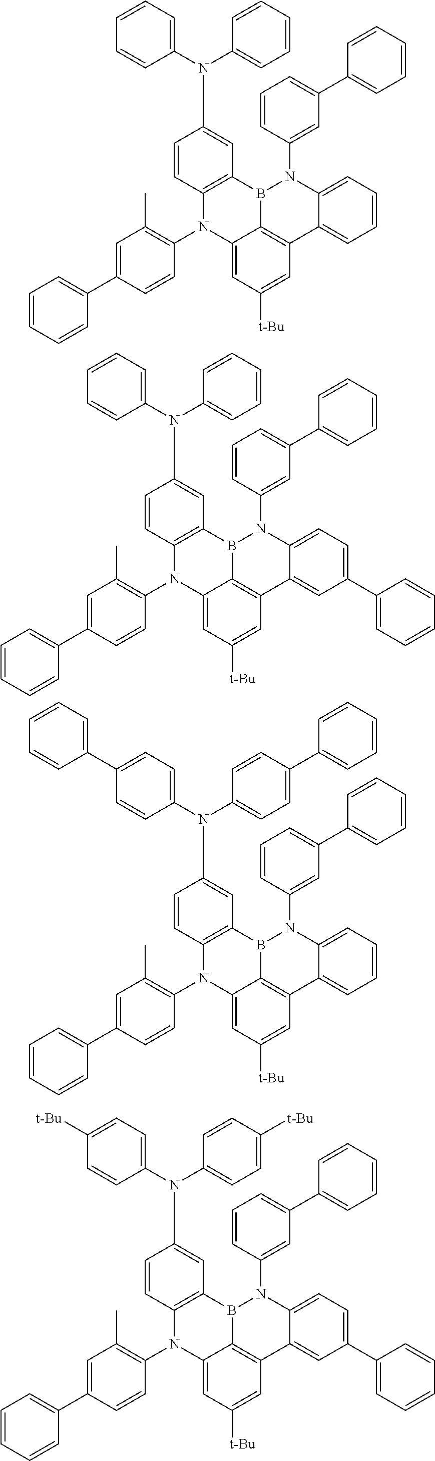 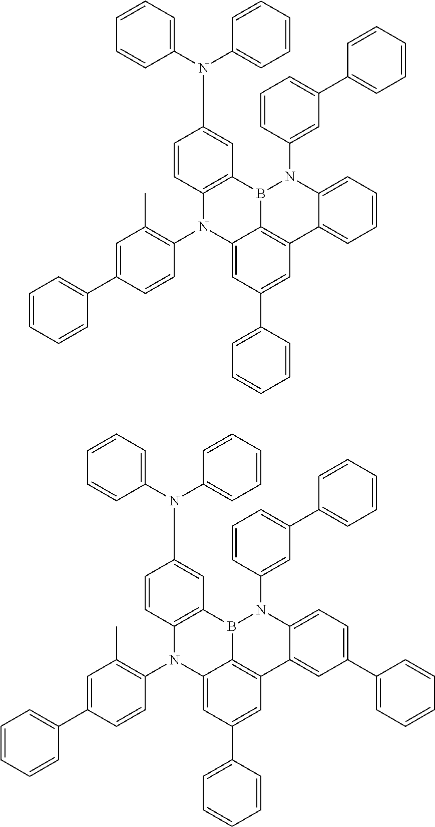 [SMILES: Cc1cc(-c2ccccc2)ccc1N1c2ccc(N(c3ccccc3)c3ccccc3)cc2B2c3c(cc(-c4ccccc4)cc31)-c1ccccc1N2c1cccc(-c2ccccc2)c1 ; Cc1cc(-c2ccccc2)ccc1N1c2ccc(N(c3ccccc3)c3ccccc3)cc2B2c3c(cc(-c4ccccc4)cc31)-c1cc(-c3ccccc3)ccc1N2c1cccc(-c2ccccc2)c1] 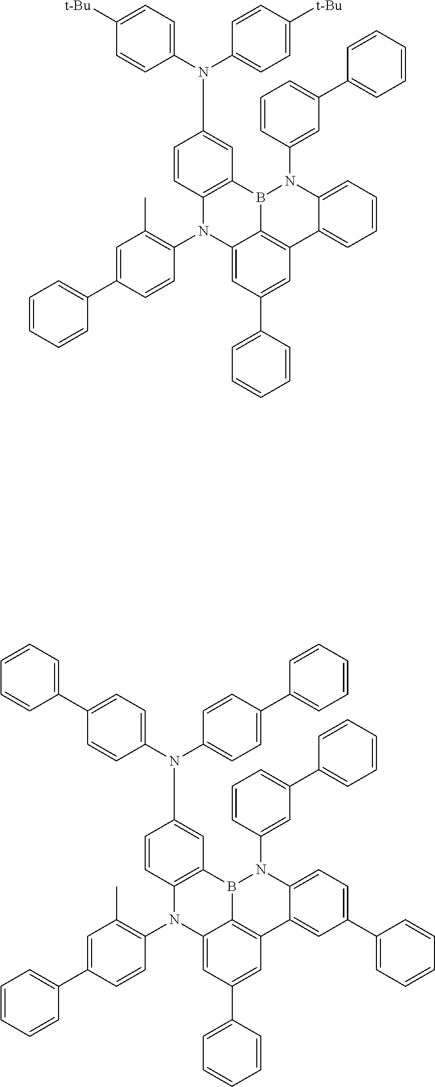 [SMILES: Cc1cc(-c2ccccc2)ccc1N1c2ccc(N(c3ccc(C(C)(C)C)cc3)c3ccc(C(C)(C)C)cc3)cc2B2c3c(cc(-c4ccccc4)cc31)-c1ccccc1N2c1cccc(-c2ccccc2)c1 ; Cc1cc(-c2ccccc2)ccc1N1c2ccc(N(c3ccc(-c4ccccc4)cc3)c3ccc(-c4ccccc4)cc3)cc2B2c3c(cc(-c4ccccc4)cc31)-c1cc(-c3ccccc3)ccc1N2c1cccc(-c2ccccc2)c1] 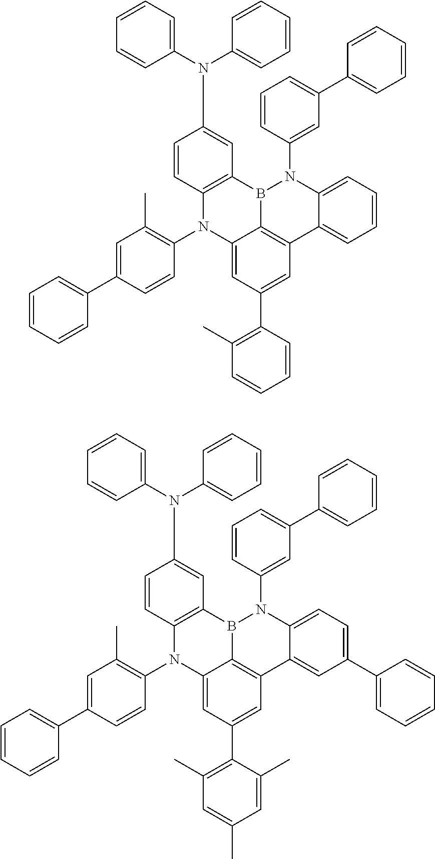 [SMILES: Cc1ccccc1-c1cc2c3c(c1)N(c1ccc(-c4ccccc4)cc1C)c1ccc(N(c4ccccc4)c4ccccc4)cc1B3N(c1cccc(-c3ccccc3)c1)c1ccccc1-2 ; Cc1cc(C)c(-c2cc3c4c(c2)N(c2ccc(-c5ccccc5)cc2C)c2ccc(N(c5ccccc5)c5ccccc5)cc2B4N(c2cccc(-c4ccccc4)c2)c2ccc(-c4ccccc4)cc2-3)c(C)c1] 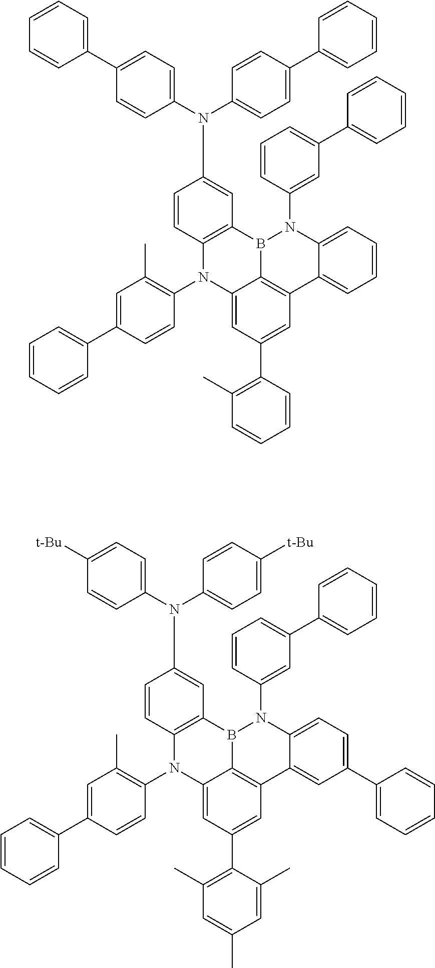 [SMILES: Cc1ccccc1-c1cc2c3c(c1)N(c1ccc(-c4ccccc4)cc1C)c1ccc(N(c4ccc(-c5ccccc5)cc4)c4ccc(-c5ccccc5)cc4)cc1B3N(c1cccc(-c3ccccc3)c1)c1ccccc1-2 ; Cc1cc(C)c(-c2cc3c4c(c2)N(c2ccc(-c5ccccc5)cc2C)c2ccc(N(c5ccc(C(C)(C)C)cc5)c5ccc(C(C)(C)C)cc5)cc2B4N(c2cccc(-c4ccccc4)c2)c2ccc(-c4ccccc4)cc2-3)c(C)c1] 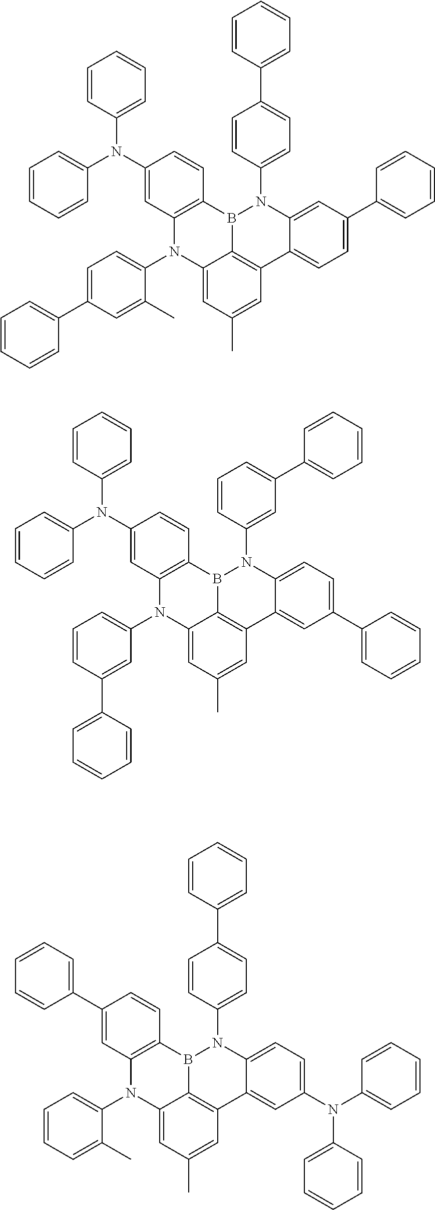 [SMILES: Cc1cc2c3c(c1)N(c1ccc(-c4ccccc4)cc1C)c1cc(N(c4ccccc4)c4ccccc4)ccc1B3N(c1ccc(-c3ccccc3)cc1)c1cc(-c3ccccc3)ccc1-2 ; Cc1cc2c3c(c1)N(c1cccc(-c4ccccc4)c1)c1cc(N(c4ccccc4)c4ccccc4)ccc1B3N(c1cccc(-c3ccccc3)c1)c1ccc(-c3ccccc3)cc1-2 ; Cc1cc2c3c(c1)N(c1ccccc1C)c1cc(-c4ccccc4)ccc1B3N(c1ccc(-c3ccccc3)cc1)c1ccc(N(c3ccccc3)c3ccccc3)cc1-2] 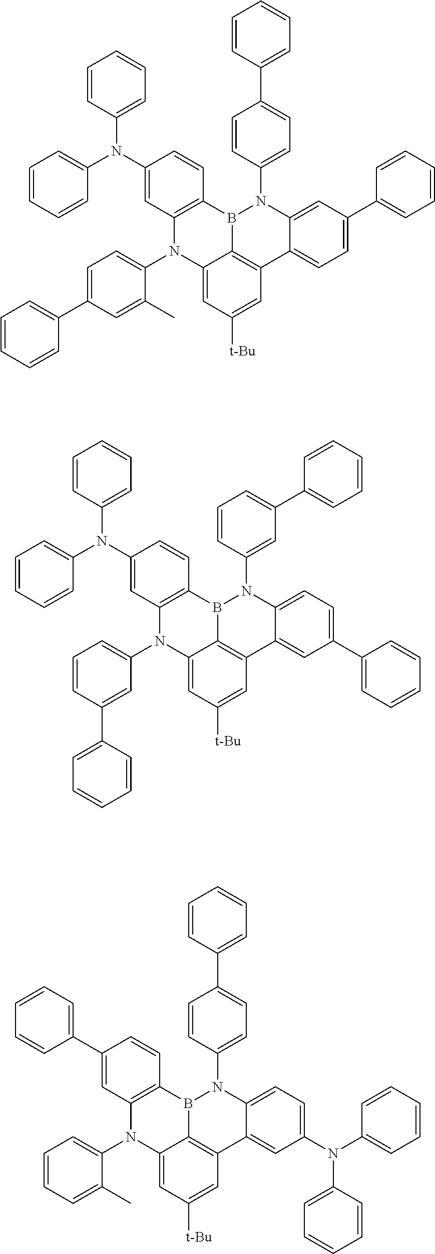 [SMILES: Cc1cc(-c2ccccc2)ccc1N1c2cc(N(c3ccccc3)c3ccccc3)ccc2B2c3c(cc(C(C)(C)C)cc31)-c1ccc(-c3ccccc3)cc1N2c1ccc(-c2ccccc2)cc1 ; CC(C)(C)c1cc2c3c(c1)N(c1cccc(-c4ccccc4)c1)c1cc(N(c4ccccc4)c4ccccc4)ccc1B3N(c1cccc(-c3ccccc3)c1)c1ccc(-c3ccccc3)cc1-2 ; Cc1ccccc1N1c2cc(-c3ccccc3)ccc2B2c3c(cc(C(C)(C)C)cc31)-c1cc(N(c3ccccc3)c3ccccc3)ccc1N2c1ccc(-c2ccccc2)cc1] 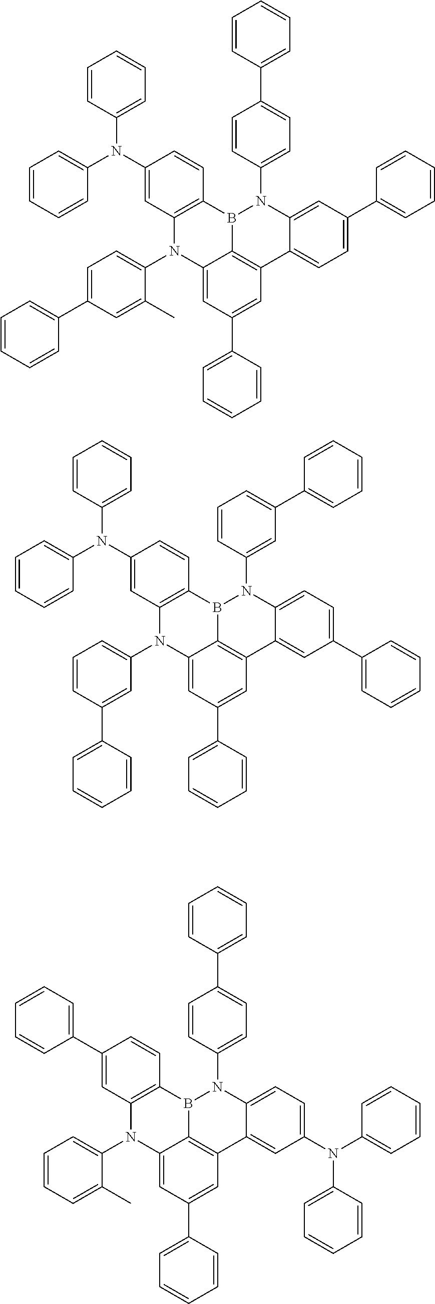 [SMILES: Cc1cc(-c2ccccc2)ccc1N1c2cc(N(c3ccccc3)c3ccccc3)ccc2B2c3c(cc(-c4ccccc4)cc31)-c1ccc(-c3ccccc3)cc1N2c1ccc(-c2ccccc2)cc1 ; c1ccc(-c2cccc(N3B4c5ccc(N(c6ccccc6)c6ccccc6)cc5N(c5cccc(-c6ccccc6)c5)c5cc(-c6ccccc6)cc(c54)-c4cc(-c5ccccc5)ccc43)c2)cc1 ; Cc1ccccc1N1c2cc(-c3ccccc3)ccc2B2c3c(cc(-c4ccccc4)cc31)-c1cc(N(c3ccccc3)c3ccccc3)ccc1N2c1ccc(-c2ccccc2)cc1] 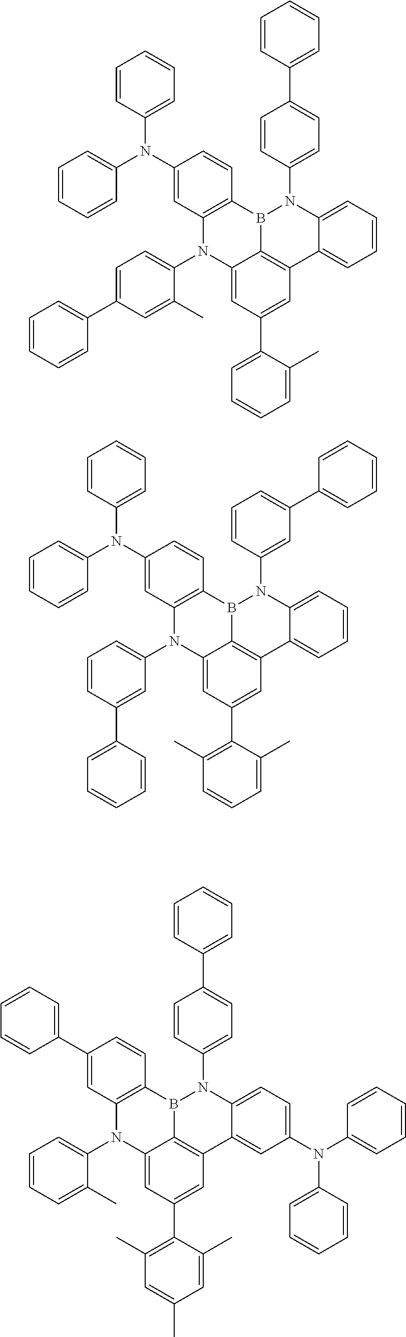 [SMILES: Cc1ccccc1-c1cc2c3c(c1)N(c1ccc(-c4ccccc4)cc1C)c1cc(N(c4ccccc4)c4ccccc4)ccc1B3N(c1ccc(-c3ccccc3)cc1)c1ccccc1-2 ; Cc1cccc(C)c1-c1cc2c3c(c1)N(c1cccc(-c4ccccc4)c1)c1cc(N(c4ccccc4)c4ccccc4)ccc1B3N(c1cccc(-c3ccccc3)c1)c1ccccc1-2 ; Cc1cc(C)c(-c2cc3c4c(c2)N(c2ccccc2C)c2cc(-c5ccccc5)ccc2B4N(c2ccc(-c4ccccc4)cc2)c2ccc(N(c4ccccc4)c4ccccc4)cc2-3)c(C)c1] 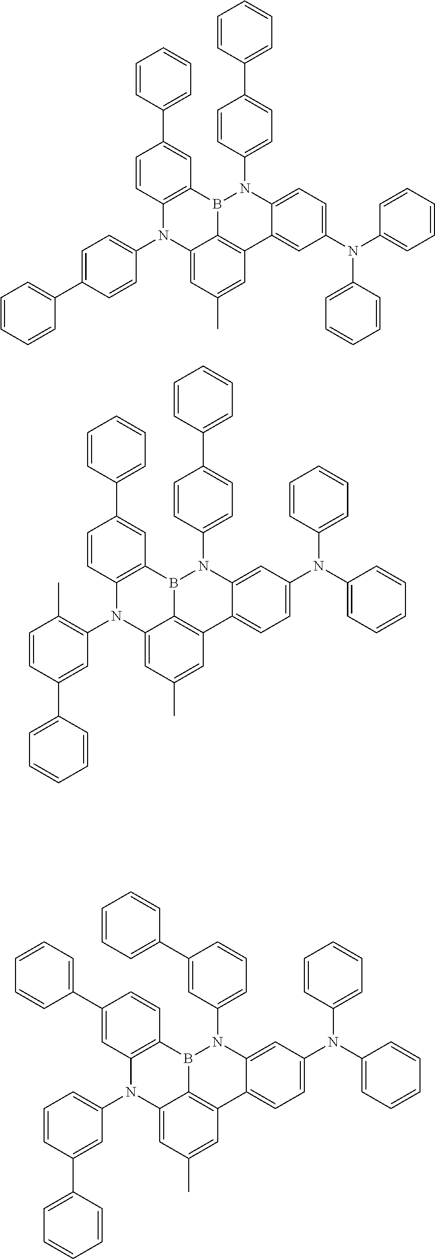 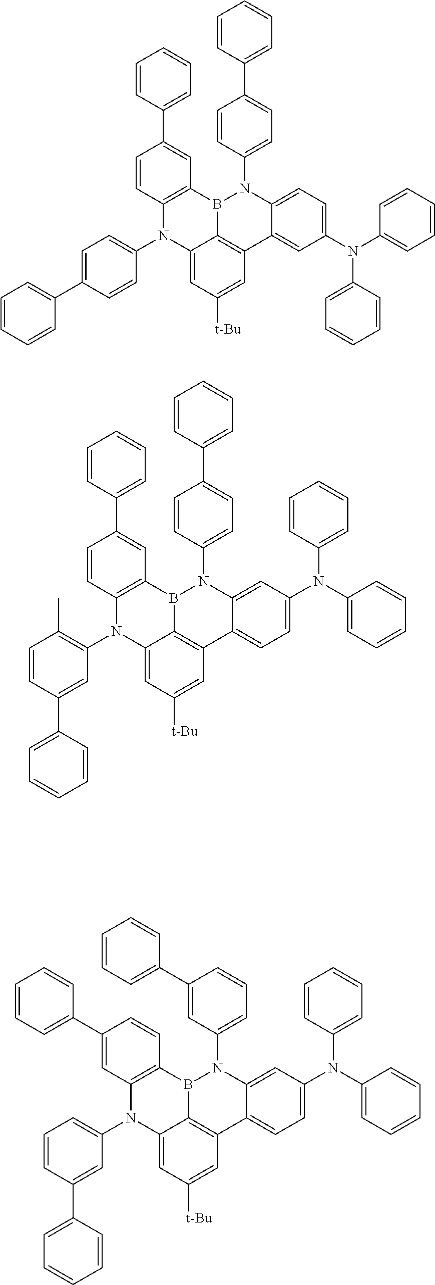 [SMILES: CC(C)(C)c1cc2c3c(c1)N(c1ccc(-c4ccccc4)cc1)c1ccc(-c4ccccc4)cc1B3N(c1ccc(-c3ccccc3)cc1)c1ccc(N(c3ccccc3)c3ccccc3)cc1-2 ; Cc1ccc(-c2ccccc2)cc1N1c2ccc(-c3ccccc3)cc2B2c3c(cc(C(C)(C)C)cc31)-c1ccc(N(c3ccccc3)c3ccccc3)cc1N2c1ccc(-c2ccccc2)cc1 ; CC(C)(C)c1cc2c3c(c1)N(c1cccc(-c4ccccc4)c1)c1cc(-c4ccccc4)ccc1B3N(c1cccc(-c3ccccc3)c1)c1cc(N(c3ccccc3)c3ccccc3)ccc1-2] 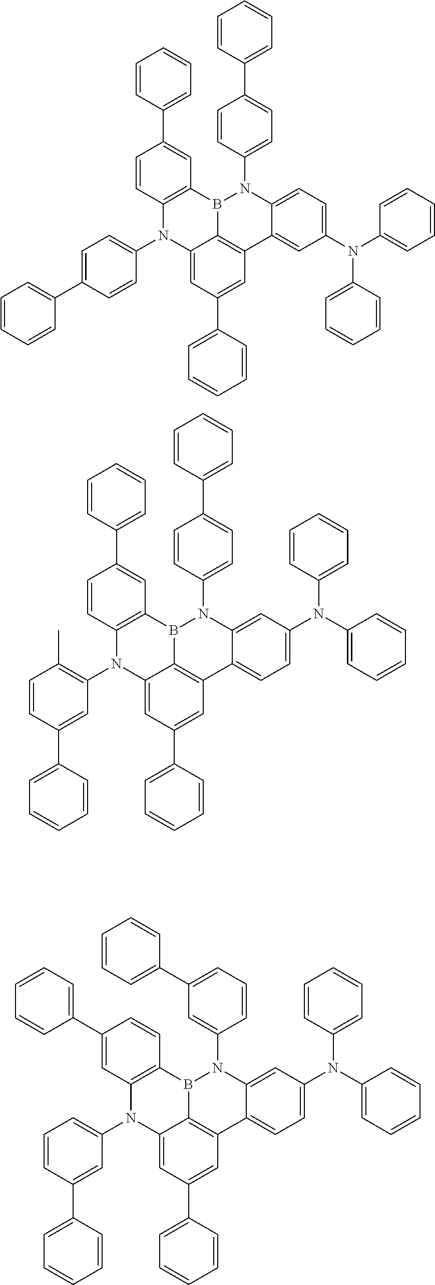 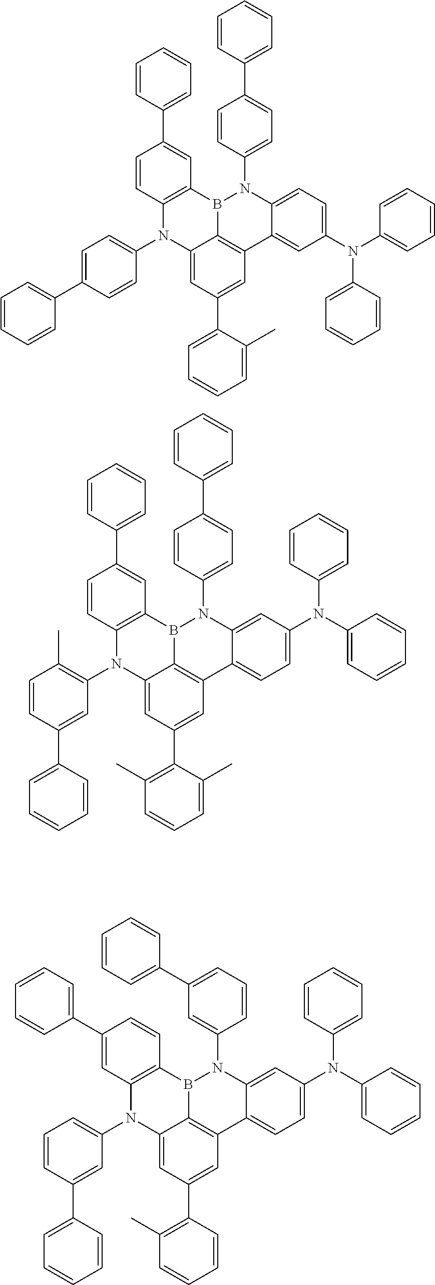 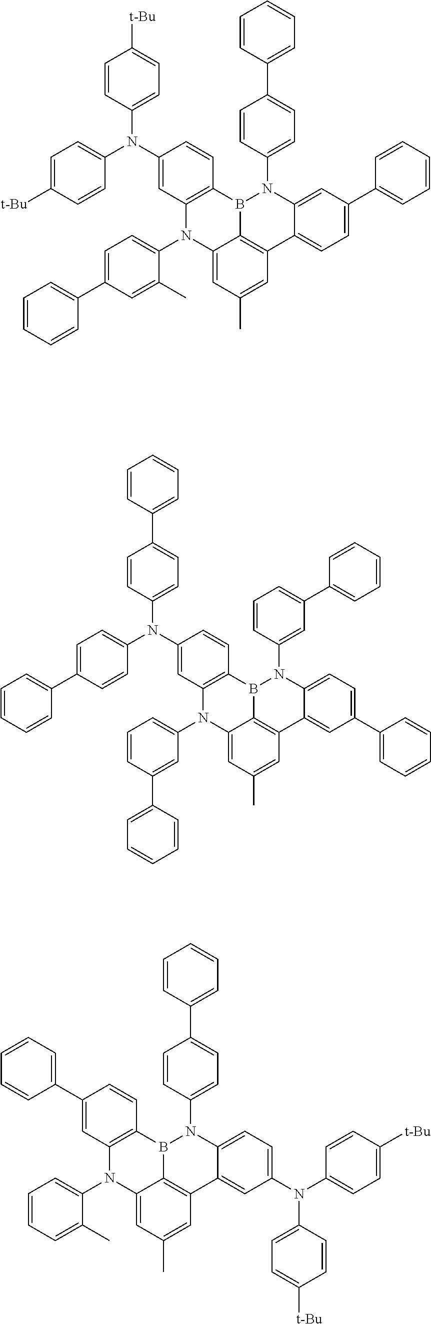 [SMILES: Cc1cc2c3c(c1)N(c1ccc(-c4ccccc4)cc1C)c1cc(N(c4ccc(C(C)(C)C)cc4)c4ccc(C(C)(C)C)cc4)ccc1B3N(c1ccc(-c3ccccc3)cc1)c1cc(-c3ccccc3)ccc1-2 ; Cc1cc2c3c(c1)N(c1cccc(-c4ccccc4)c1)c1cc(N(c4ccc(-c5ccccc5)cc4)c4ccc(-c5ccccc5)cc4)ccc1B3N(c1cccc(-c3ccccc3)c1)c1ccc(-c3ccccc3)cc1-2 ; Cc1cc2c3c(c1)N(c1ccccc1C)c1cc(-c4ccccc4)ccc1B3N(c1ccc(-c3ccccc3)cc1)c1ccc(N(c3ccc(C(C)(C)C)cc3)c3ccc(C(C)(C)C)cc3)cc1-2] 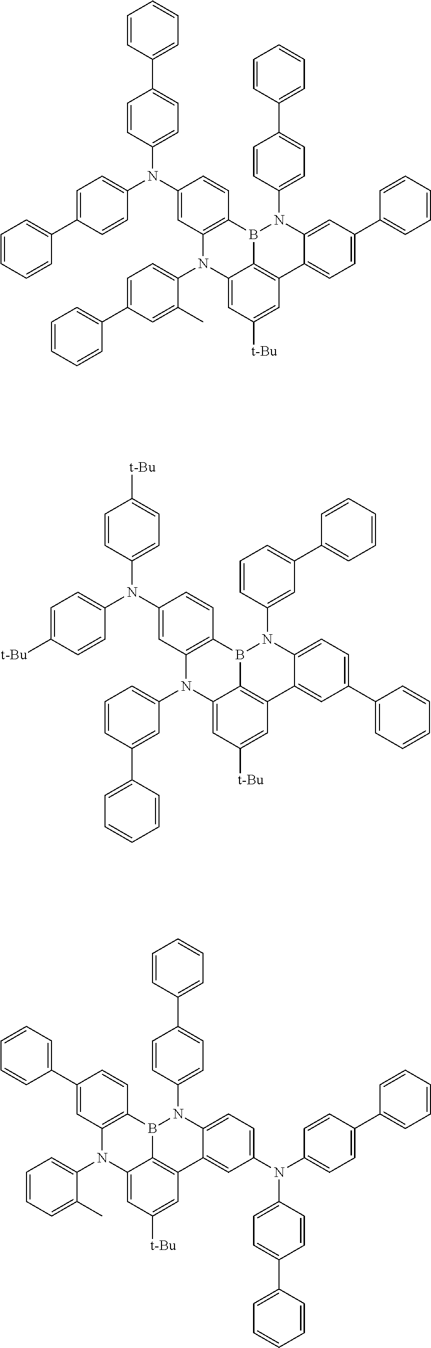 [SMILES: Cc1cc(-c2ccccc2)ccc1N1c2cc(N(c3ccc(-c4ccccc4)cc3)c3ccc(-c4ccccc4)cc3)ccc2B2c3c(cc(C(C)(C)C)cc31)-c1ccc(-c3ccccc3)cc1N2c1ccc(-c2ccccc2)cc1 ; CC(C)(C)c1ccc(N(c2ccc(C(C)(C)C)cc2)c2ccc3c(c2)N(c2cccc(-c4ccccc4)c2)c2cc(C(C)(C)C)cc4c2B3N(c2cccc(-c3ccccc3)c2)c2ccc(-c3ccccc3)cc2-4)cc1 ; Cc1ccccc1N1c2cc(-c3ccccc3)ccc2B2c3c(cc(C(C)(C)C)cc31)-c1cc(N(c3ccc(-c4ccccc4)cc3)c3ccc(-c4ccccc4)cc3)ccc1N2c1ccc(-c2ccccc2)cc1] 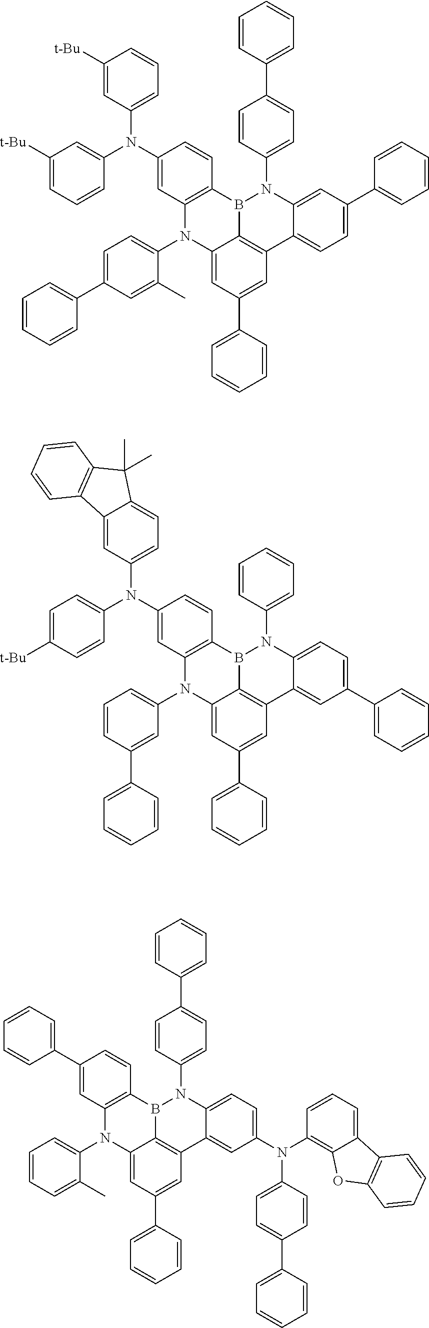 [SMILES: Cc1cc(-c2ccccc2)ccc1N1c2cc(N(c3cccc(C(C)(C)C)c3)c3cccc(C(C)(C)C)c3)ccc2B2c3c(cc(-c4ccccc4)cc31)-c1ccc(-c3ccccc3)cc1N2c1ccc(-c2ccccc2)cc1 ; CC(C)(C)c1ccc(N(c2ccc3c(c2)-c2ccccc2C3(C)C)c2ccc3c(c2)N(c2cccc(-c4ccccc4)c2)c2cc(-c4ccccc4)cc4c2B3N(c2ccccc2)c2ccc(-c3ccccc3)cc2-4)cc1 ; Cc1ccccc1N1c2cc(-c3ccccc3)ccc2B2c3c(cc(-c4ccccc4)cc31)-c1cc(N(c3ccc(-c4ccccc4)cc3)c3cccc4c3oc3ccccc34)ccc1N2c1ccc(-c2ccccc2)cc1] 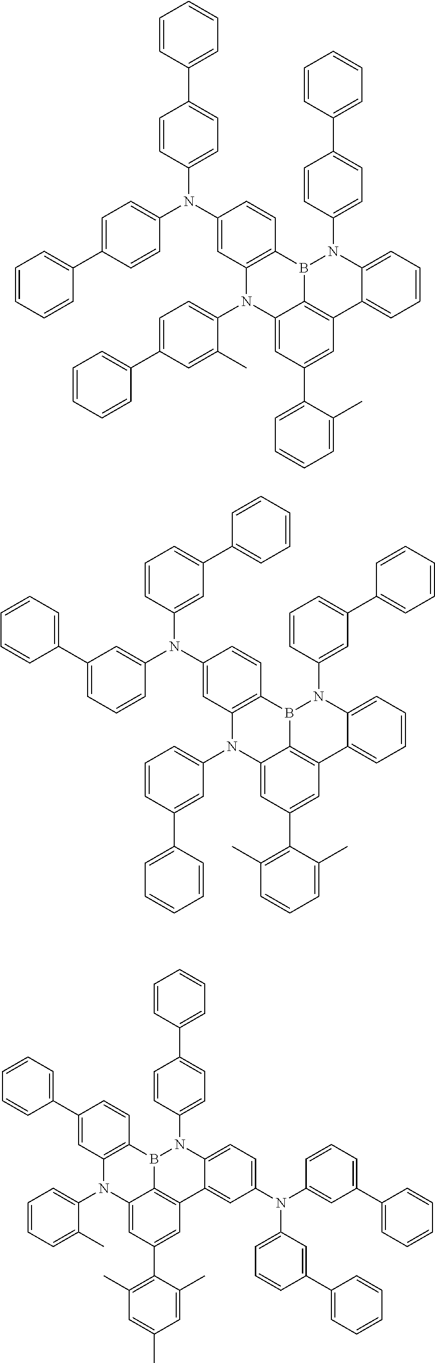 [SMILES: Cc1ccccc1-c1cc2c3c(c1)N(c1ccc(-c4ccccc4)cc1C)c1cc(N(c4ccc(-c5ccccc5)cc4)c4ccc(-c5ccccc5)cc4)ccc1B3N(c1ccc(-c3ccccc3)cc1)c1ccccc1-2 ; Cc1cccc(C)c1-c1cc2c3c(c1)N(c1cccc(-c4ccccc4)c1)c1cc(N(c4cccc(-c5ccccc5)c4)c4cccc(-c5ccccc5)c4)ccc1B3N(c1cccc(-c3ccccc3)c1)c1ccccc1-2 ; Cc1cc(C)c(-c2cc3c4c(c2)N(c2ccccc2C)c2cc(-c5ccccc5)ccc2B4N(c2ccc(-c4ccccc4)cc2)c2ccc(N(c4cccc(-c5ccccc5)c4)c4cccc(-c5ccccc5)c4)cc2-3)c(C)c1] 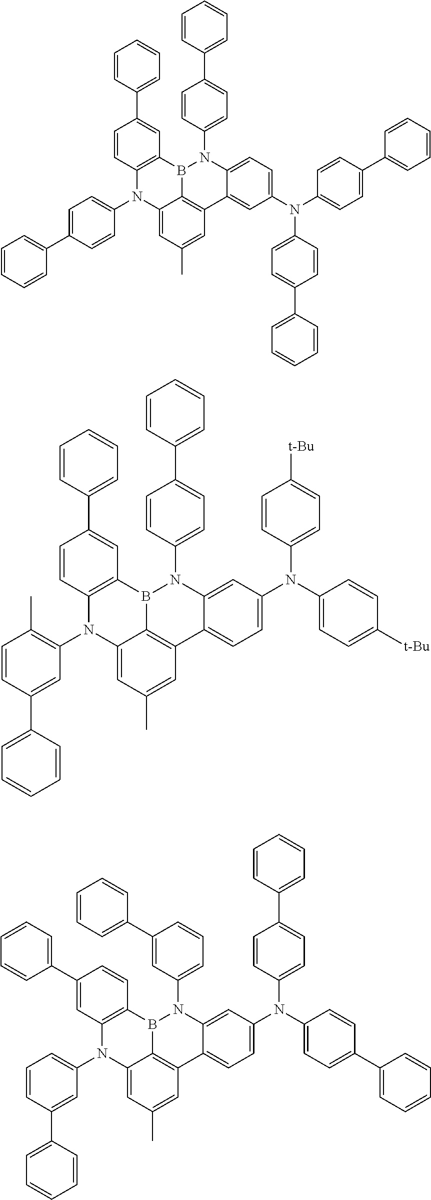 [SMILES: Cc1cc2c3c(c1)N(c1ccc(-c4ccccc4)cc1)c1ccc(-c4ccccc4)cc1B3N(c1ccc(-c3ccccc3)cc1)c1ccc(N(c3ccc(-c4ccccc4)cc3)c3ccc(-c4ccccc4)cc3)cc1-2 ; Cc1cc2c3c(c1)N(c1cc(-c4ccccc4)ccc1C)c1ccc(-c4ccccc4)cc1B3N(c1ccc(-c3ccccc3)cc1)c1cc(N(c3ccc(C(C)(C)C)cc3)c3ccc(C(C)(C)C)cc3)ccc1-2 ; Cc1cc2c3c(c1)N(c1cccc(-c4ccccc4)c1)c1cc(-c4ccccc4)ccc1B3N(c1cccc(-c3ccccc3)c1)c1cc(N(c3ccc(-c4ccccc4)cc3)c3ccc(-c4ccccc4)cc3)ccc1-2] 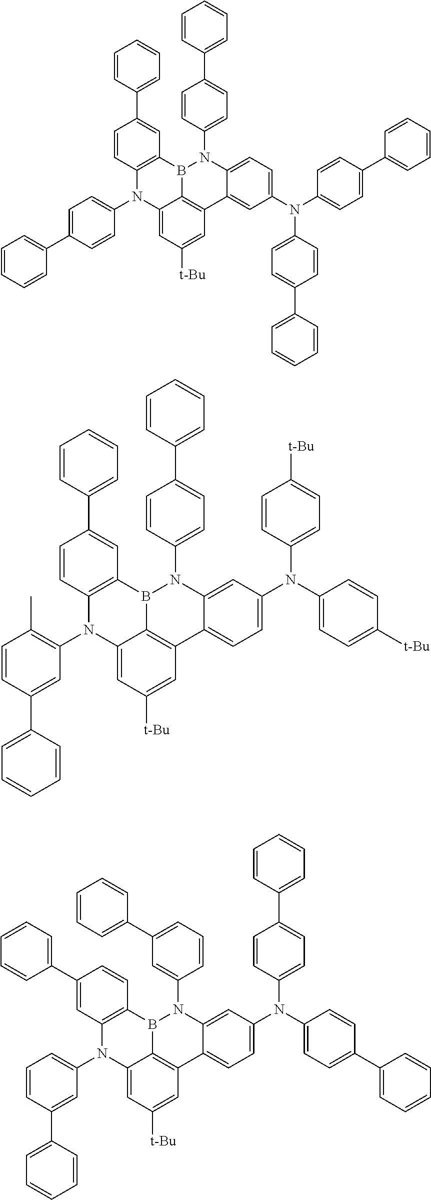 [SMILES: CC(C)(C)c1cc2c3c(c1)N(c1ccc(-c4ccccc4)cc1)c1ccc(-c4ccccc4)cc1B3N(c1ccc(-c3ccccc3)cc1)c1ccc(N(c3ccc(-c4ccccc4)cc3)c3ccc(-c4ccccc4)cc3)cc1-2 ; Cc1ccc(-c2ccccc2)cc1N1c2ccc(-c3ccccc3)cc2B2c3c(cc(C(C)(C)C)cc31)-c1ccc(N(c3ccc(C(C)(C)C)cc3)c3ccc(C(C)(C)C)cc3)cc1N2c1ccc(-c2ccccc2)cc1 ; CC(C)(C)c1cc2c3c(c1)N(c1cccc(-c4ccccc4)c1)c1cc(-c4ccccc4)ccc1B3N(c1cccc(-c3ccccc3)c1)c1cc(N(c3ccc(-c4ccccc4)cc3)c3ccc(-c4ccccc4)cc3)ccc1-2] 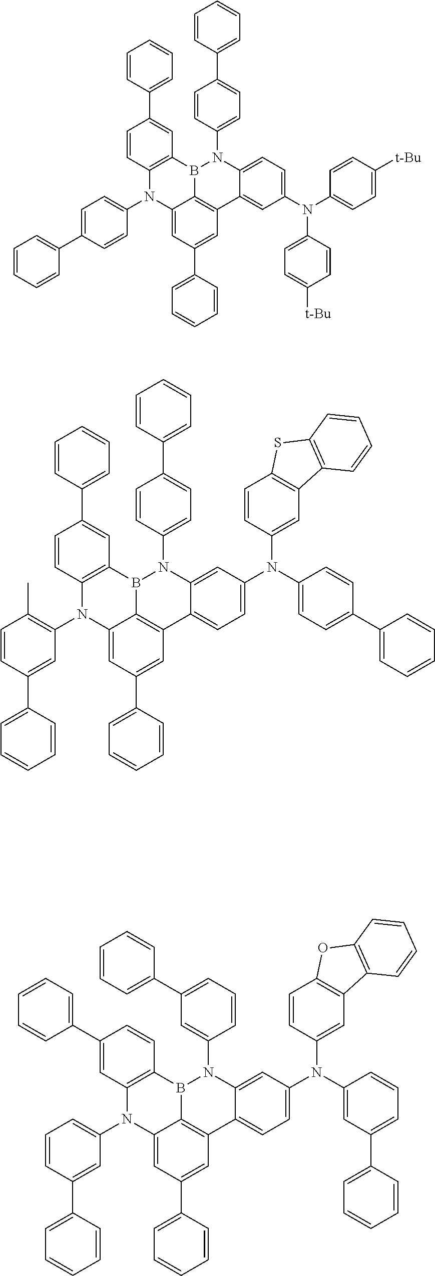 [SMILES: CC(C)(C)c1ccc(N(c2ccc(C(C)(C)C)cc2)c2ccc3c(c2)-c2cc(-c4ccccc4)cc4c2B(c2cc(-c5ccccc5)ccc2N4c2ccc(-c4ccccc4)cc2)N3c2ccc(-c3ccccc3)cc2)cc1 ; Cc1ccc(-c2ccccc2)cc1N1c2ccc(-c3ccccc3)cc2B2c3c(cc(-c4ccccc4)cc31)-c1ccc(N(c3ccc(-c4ccccc4)cc3)c3ccc4sc5ccccc5c4c3)cc1N2c1ccc(-c2ccccc2)cc1 ; c1ccc(-c2cccc(N3B4c5ccc(-c6ccccc6)cc5N(c5cccc(-c6ccccc6)c5)c5cc(-c6ccccc6)cc(c54)-c4ccc(N(c5cccc(-c6ccccc6)c5)c5ccc6oc7ccccc7c6c5)cc43)c2)cc1] 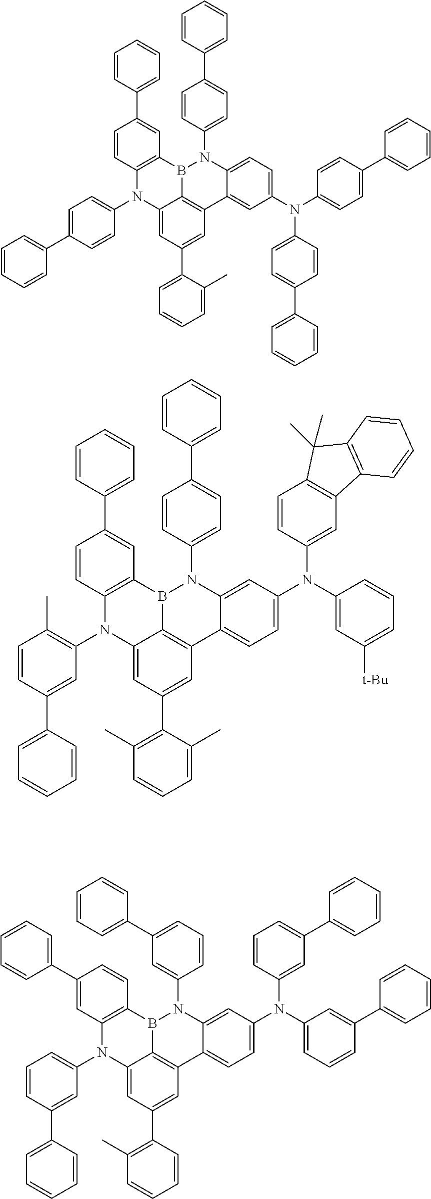 [SMILES: Cc1ccccc1-c1cc2c3c(c1)N(c1ccc(-c4ccccc4)cc1)c1ccc(-c4ccccc4)cc1B3N(c1ccc(-c3ccccc3)cc1)c1ccc(N(c3ccc(-c4ccccc4)cc3)c3ccc(-c4ccccc4)cc3)cc1-2 ; Cc1ccc(-c2ccccc2)cc1N1c2ccc(-c3ccccc3)cc2B2c3c(cc(-c4c(C)cccc4C)cc31)-c1ccc(N(c3cccc(C(C)(C)C)c3)c3ccc4c(c3)-c3ccccc3C4(C)C)cc1N2c1ccc(-c2ccccc2)cc1 ; Cc1ccccc1-c1cc2c3c(c1)N(c1cccc(-c4ccccc4)c1)c1cc(-c4ccccc4)ccc1B3N(c1cccc(-c3ccccc3)c1)c1cc(N(c3cccc(-c4ccccc4)c3)c3cccc(-c4ccccc4)c3)ccc1-2] 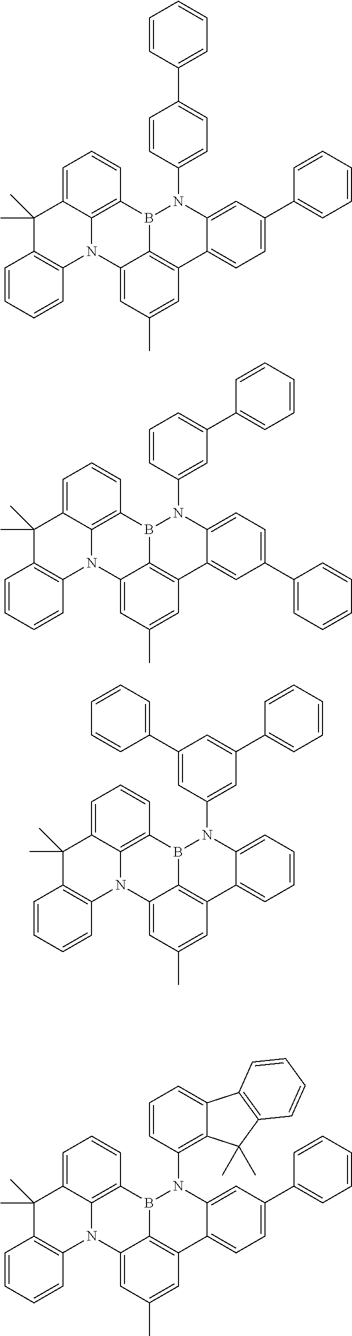 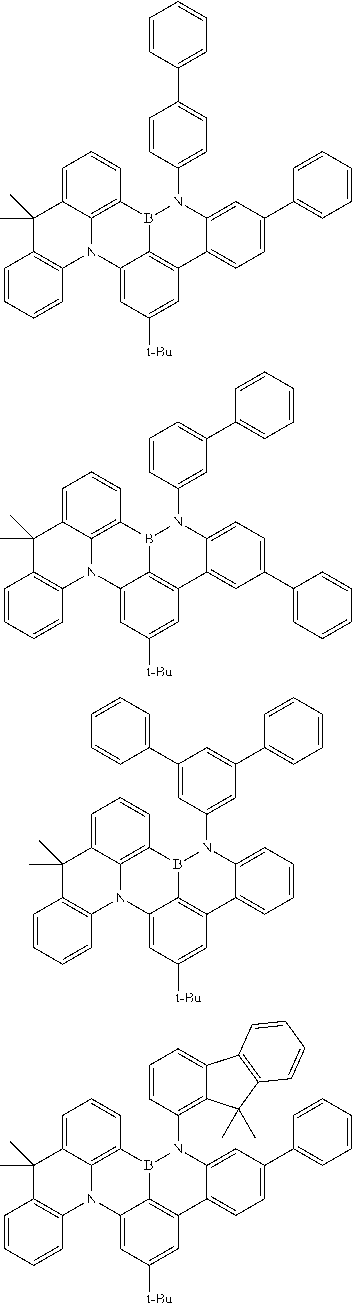 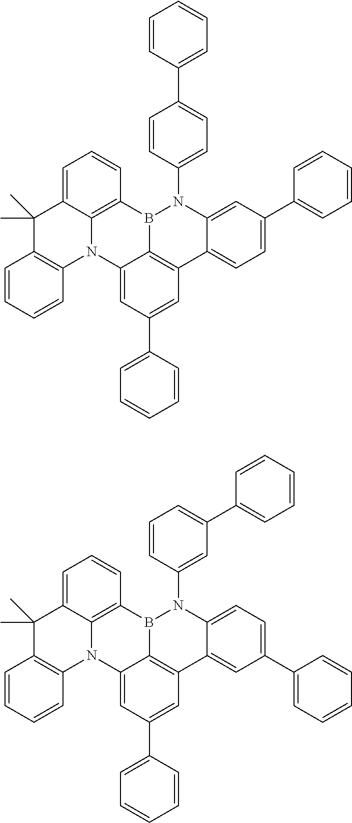 [SMILES: CC1(C)c2ccccc2N2c3cc(-c4ccccc4)cc4c3B(c3cccc1c32)N(c1ccc(-c2ccccc2)cc1)c1cc(-c2ccccc2)ccc1-4 ; CC1(C)c2ccccc2N2c3cc(-c4ccccc4)cc4c3B(c3cccc1c32)N(c1cccc(-c2ccccc2)c1)c1ccc(-c2ccccc2)cc1-4] 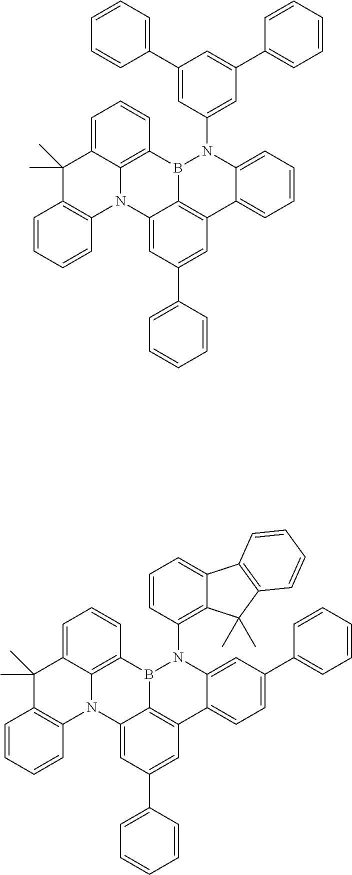 [SMILES: CC1(C)c2ccccc2N2c3cc(-c4ccccc4)cc4c3B(c3cccc1c32)N(c1cc(-c2ccccc2)cc(-c2ccccc2)c1)c1ccccc1-4 ; CC1(C)c2ccccc2N2c3cc(-c4ccccc4)cc4c3B(c3cccc1c32)N(c1cccc2c1C(C)(C)c1ccccc1-2)c1cc(-c2ccccc2)ccc1-4] 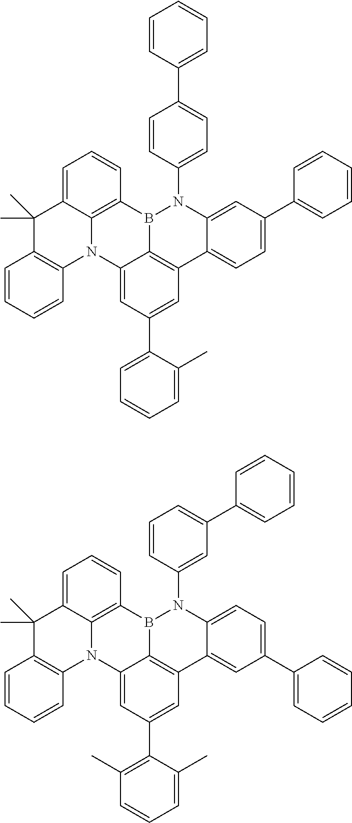 [SMILES: Cc1ccccc1-c1cc2c3c(c1)N1c4ccccc4C(C)(C)c4cccc(c41)B3N(c1ccc(-c3ccccc3)cc1)c1cc(-c3ccccc3)ccc1-2 ; Cc1cccc(C)c1-c1cc2c3c(c1)N1c4ccccc4C(C)(C)c4cccc(c41)B3N(c1cccc(-c3ccccc3)c1)c1ccc(-c3ccccc3)cc1-2] 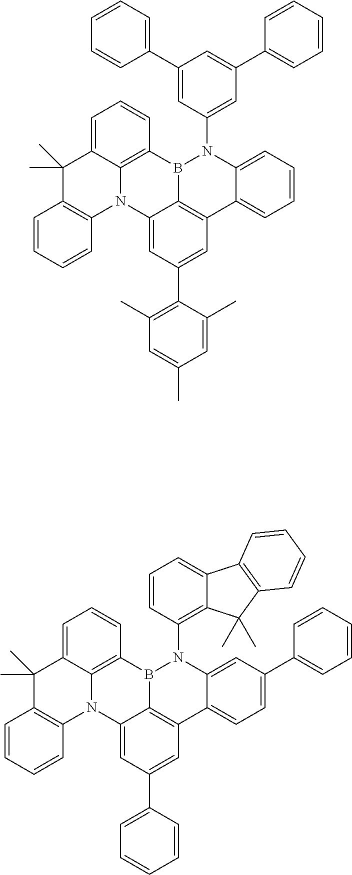 [SMILES: Cc1cc(C)c(-c2cc3c4c(c2)N2c5ccccc5C(C)(C)c5cccc(c52)B4N(c2cc(-c4ccccc4)cc(-c4ccccc4)c2)c2ccccc2-3)c(C)c1 ; CC1(C)c2ccccc2N2c3cc(-c4ccccc4)cc4c3B(c3cccc1c32)N(c1cccc2c1C(C)(C)c1ccccc1-2)c1cc(-c2ccccc2)ccc1-4] 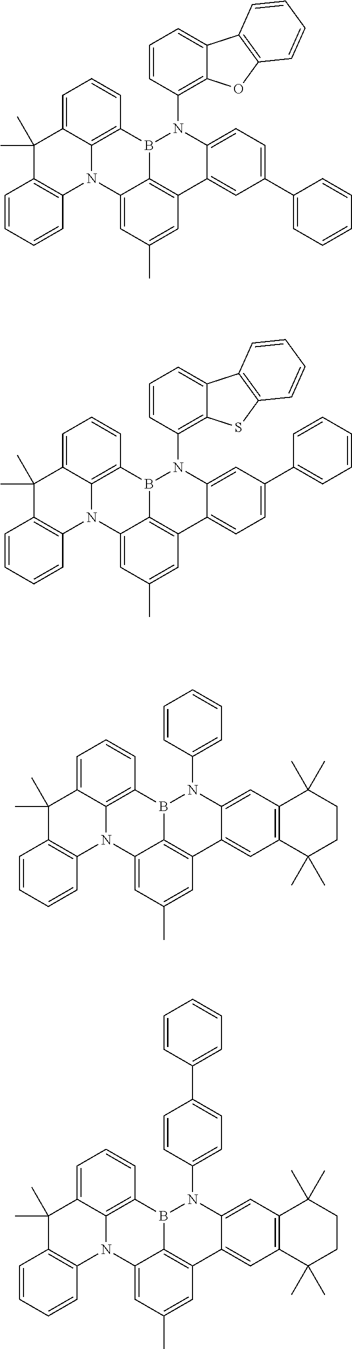 [SMILES: Cc1cc2c3c(c1)N1c4ccccc4C(C)(C)c4cccc(c41)B3N(c1cccc3c1oc1ccccc13)c1ccc(-c3ccccc3)cc1-2 ; Cc1cc2c3c(c1)N1c4ccccc4C(C)(C)c4cccc(c41)B3N(c1cccc3c1sc1ccccc13)c1cc(-c3ccccc3)ccc1-2 ; Cc1cc2c3c(c1)N1c4ccccc4C(C)(C)c4cccc(c41)B3N(c1ccccc1)c1cc3c(cc1-2)C(C)(C)CCC3(C)C ; Cc1cc2c3c(c1)N1c4ccccc4C(C)(C)c4cccc(c41)B3N(c1ccc(-c3ccccc3)cc1)c1cc3c(cc1-2)C(C)(C)CCC3(C)C] 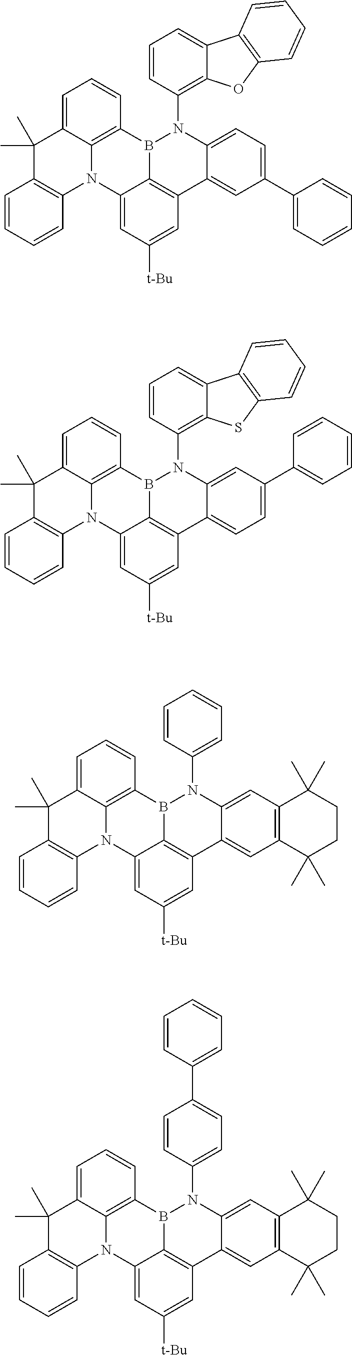 [SMILES: CC(C)(C)c1cc2c3c(c1)N1c4ccccc4C(C)(C)c4cccc(c41)B3N(c1cccc3c1oc1ccccc13)c1ccc(-c3ccccc3)cc1-2 ; CC(C)(C)c1cc2c3c(c1)N1c4ccccc4C(C)(C)c4cccc(c41)B3N(c1cccc3c1sc1ccccc13)c1cc(-c3ccccc3)ccc1-2 ; CC(C)(C)c1cc2c3c(c1)N1c4ccccc4C(C)(C)c4cccc(c41)B3N(c1ccccc1)c1cc3c(cc1-2)C(C)(C)CCC3(C)C ; CC(C)(C)c1cc2c3c(c1)N1c4ccccc4C(C)(C)c4cccc(c41)B3N(c1ccc(-c3ccccc3)cc1)c1cc3c(cc1-2)C(C)(C)CCC3(C)C] 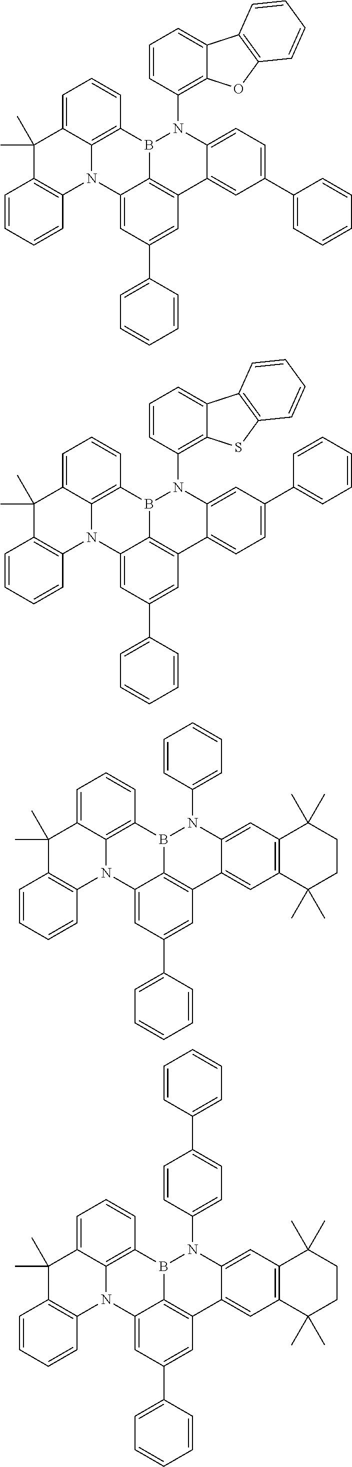 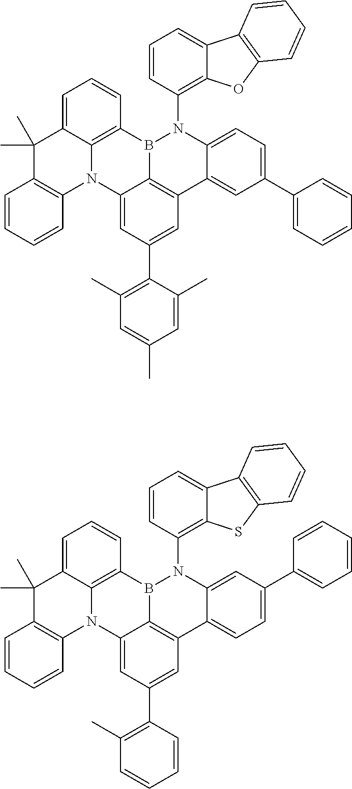 [SMILES: Cc1cc(C)c(-c2cc3c4c(c2)N2c5ccccc5C(C)(C)c5cccc(c52)B4N(c2cccc4c2oc2ccccc24)c2ccc(-c4ccccc4)cc2-3)c(C)c1 ; Cc1ccccc1-c1cc2c3c(c1)N1c4ccccc4C(C)(C)c4cccc(c41)B3N(c1cccc3c1sc1ccccc13)c1cc(-c3ccccc3)ccc1-2] 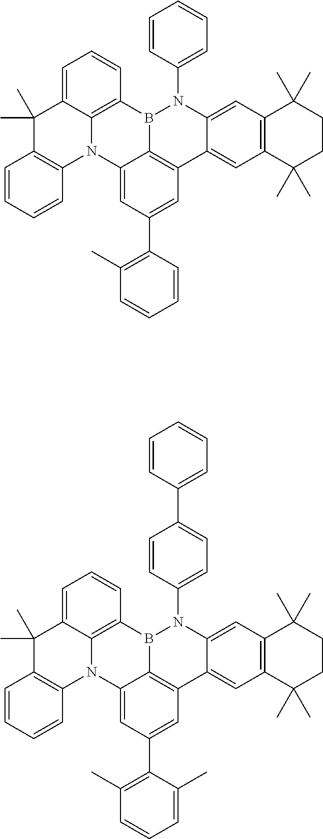 [SMILES: Cc1ccccc1-c1cc2c3c(c1)N1c4ccccc4C(C)(C)c4cccc(c41)B3N(c1ccccc1)c1cc3c(cc1-2)C(C)(C)CCC3(C)C ; Cc1cccc(C)c1-c1cc2c3c(c1)N1c4ccccc4C(C)(C)c4cccc(c41)B3N(c1ccc(-c3ccccc3)cc1)c1cc3c(cc1-2)C(C)(C)CCC3(C)C] 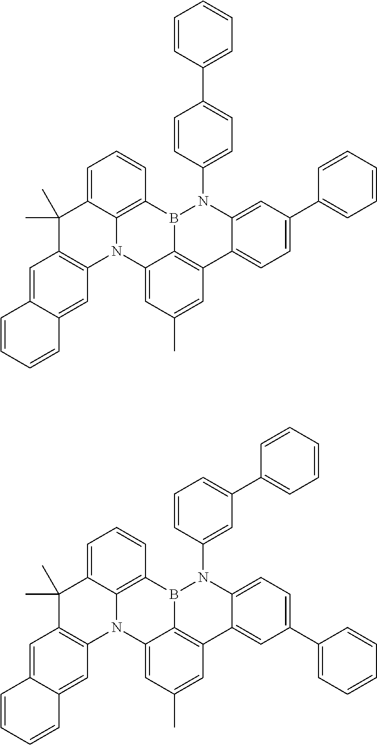 [SMILES: Cc1cc2c3c(c1)N1c4cc5ccccc5cc4C(C)(C)c4cccc(c41)B3N(c1ccc(-c3ccccc3)cc1)c1cc(-c3ccccc3)ccc1-2 ; Cc1cc2c3c(c1)N1c4cc5ccccc5cc4C(C)(C)c4cccc(c41)B3N(c1cccc(-c3ccccc3)c1)c1ccc(-c3ccccc3)cc1-2] 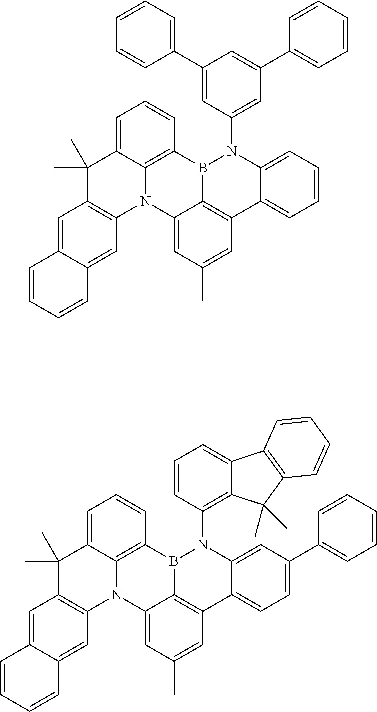 [SMILES: Cc1cc2c3c(c1)N1c4cc5ccccc5cc4C(C)(C)c4cccc(c41)B3N(c1cc(-c3ccccc3)cc(-c3ccccc3)c1)c1ccccc1-2 ; Cc1cc2c3c(c1)N1c4cc5ccccc5cc4C(C)(C)c4cccc(c41)B3N(c1cccc3c1C(C)(C)c1ccccc1-3)c1cc(-c3ccccc3)ccc1-2] 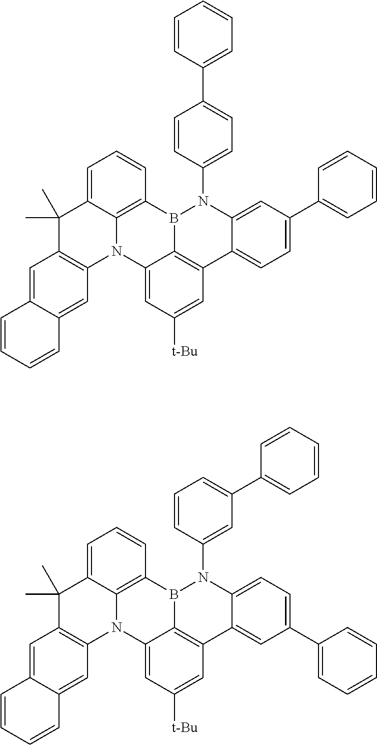 [SMILES: CC(C)(C)c1cc2c3c(c1)N1c4cc5ccccc5cc4C(C)(C)c4cccc(c41)B3N(c1ccc(-c3ccccc3)cc1)c1cc(-c3ccccc3)ccc1-2 ; CC(C)(C)c1cc2c3c(c1)N1c4cc5ccccc5cc4C(C)(C)c4cccc(c41)B3N(c1cccc(-c3ccccc3)c1)c1ccc(-c3ccccc3)cc1-2] 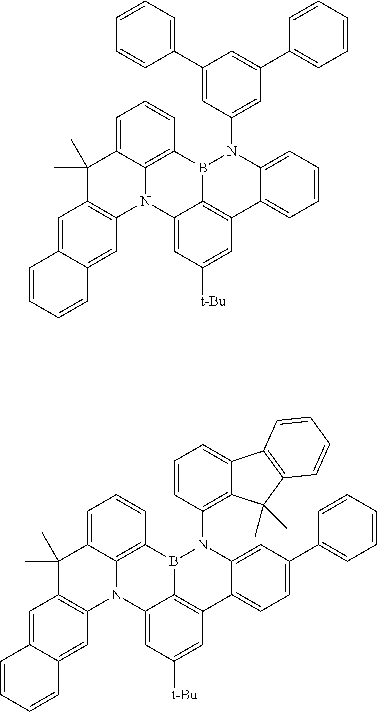 [SMILES: CC(C)(C)c1cc2c3c(c1)N1c4cc5ccccc5cc4C(C)(C)c4cccc(c41)B3N(c1cc(-c3ccccc3)cc(-c3ccccc3)c1)c1ccccc1-2 ; CC(C)(C)c1cc2c3c(c1)N1c4cc5ccccc5cc4C(C)(C)c4cccc(c41)B3N(c1cccc3c1C(C)(C)c1ccccc1-3)c1cc(-c3ccccc3)ccc1-2] 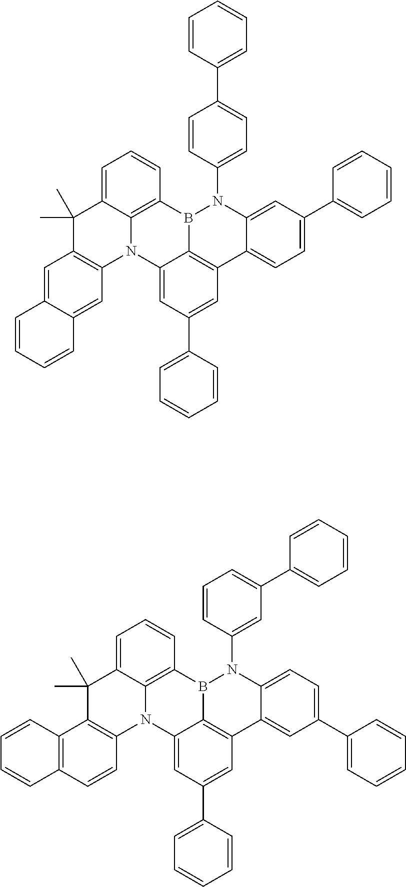 [SMILES: CC1(C)c2cc3ccccc3cc2N2c3cc(-c4ccccc4)cc4c3B(c3cccc1c32)N(c1ccc(-c2ccccc2)cc1)c1cc(-c2ccccc2)ccc1-4 ; CC1(C)c2cccc3c2N(c2cc(-c4ccccc4)cc4c2B3N(c2cccc(-c3ccccc3)c2)c2ccc(-c3ccccc3)cc2-4)c2ccc3ccccc3c21] 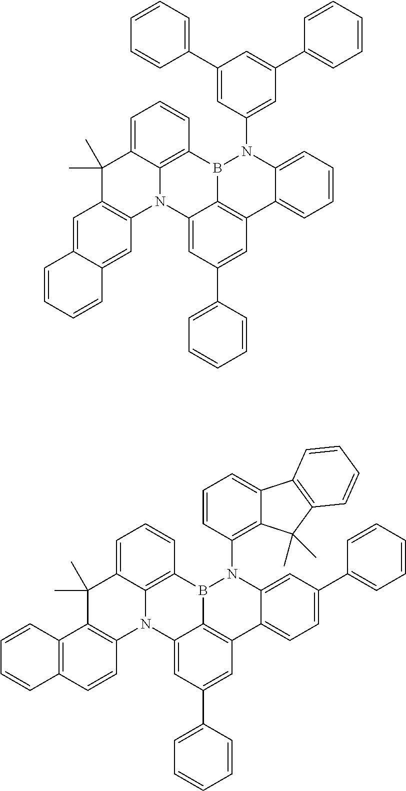 [SMILES: CC1(C)c2cc3ccccc3cc2N2c3cc(-c4ccccc4)cc4c3B(c3cccc1c32)N(c1cc(-c2ccccc2)cc(-c2ccccc2)c1)c1ccccc1-4 ; CC1(C)c2ccccc2-c2cccc(N3B4c5cccc6c5N(c5cc(-c7ccccc7)cc(c54)-c4ccc(-c5ccccc5)cc43)c3ccc4ccccc4c3C6(C)C)c21] 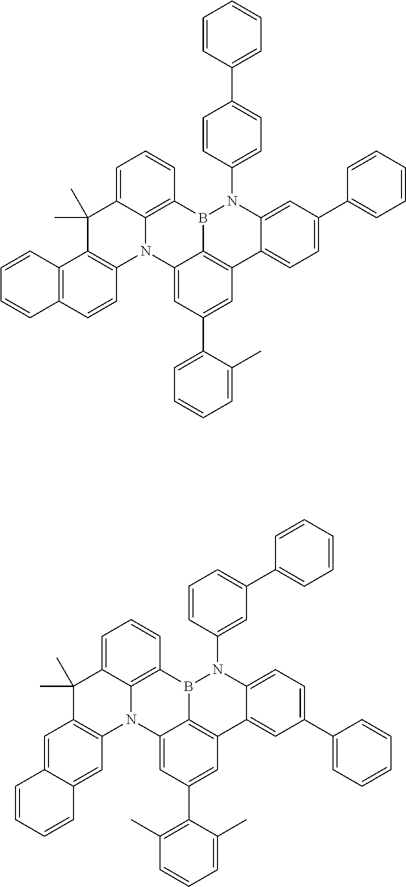 [SMILES: Cc1ccccc1-c1cc2c3c(c1)N1c4ccc5ccccc5c4C(C)(C)c4cccc(c41)B3N(c1ccc(-c3ccccc3)cc1)c1cc(-c3ccccc3)ccc1-2 ; Cc1cccc(C)c1-c1cc2c3c(c1)N1c4cc5ccccc5cc4C(C)(C)c4cccc(c41)B3N(c1cccc(-c3ccccc3)c1)c1ccc(-c3ccccc3)cc1-2] 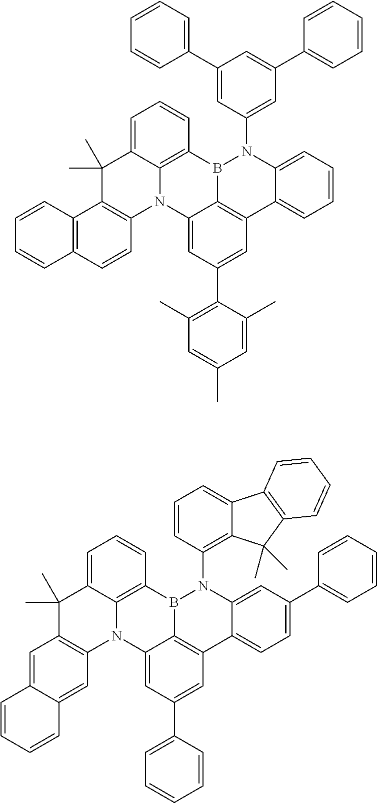 [SMILES: Cc1cc(C)c(-c2cc3c4c(c2)N2c5ccc6ccccc6c5C(C)(C)c5cccc(c52)B4N(c2cc(-c4ccccc4)cc(-c4ccccc4)c2)c2ccccc2-3)c(C)c1 ; CC1(C)c2cc3ccccc3cc2N2c3cc(-c4ccccc4)cc4c3B(c3cccc1c32)N(c1cccc2c1C(C)(C)c1ccccc1-2)c1cc(-c2ccccc2)ccc1-4] 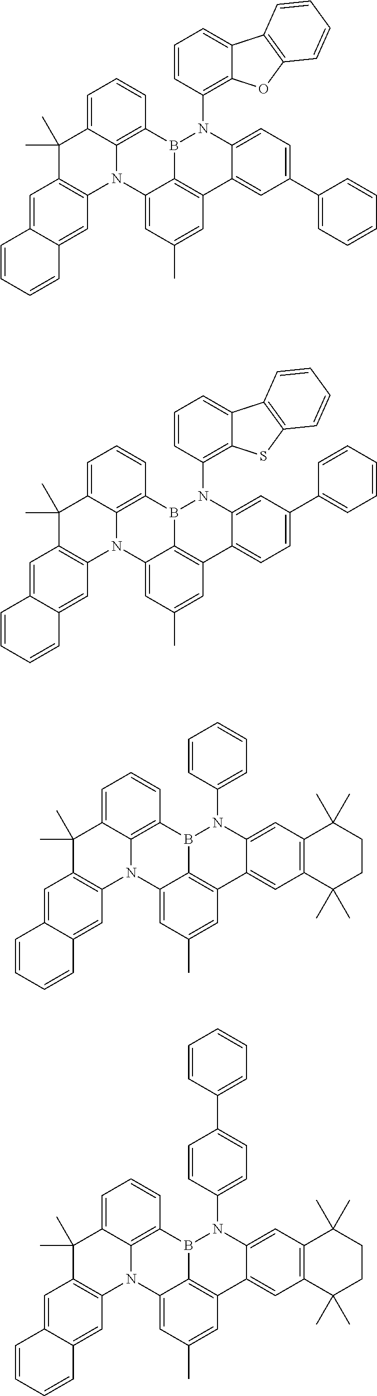 [SMILES: Cc1cc2c3c(c1)N1c4cc5ccccc5cc4C(C)(C)c4cccc(c41)B3N(c1cccc3c1oc1ccccc13)c1ccc(-c3ccccc3)cc1-2 ; Cc1cc2c3c(c1)N1c4cc5ccccc5cc4C(C)(C)c4cccc(c41)B3N(c1cccc3c1sc1ccccc13)c1cc(-c3ccccc3)ccc1-2 ; Cc1cc2c3c(c1)N1c4cc5ccccc5cc4C(C)(C)c4cccc(c41)B3N(c1ccccc1)c1cc3c(cc1-2)C(C)(C)CCC3(C)C ; Cc1cc2c3c(c1)N1c4cc5ccccc5cc4C(C)(C)c4cccc(c41)B3N(c1ccc(-c3ccccc3)cc1)c1cc3c(cc1-2)C(C)(C)CCC3(C)C] 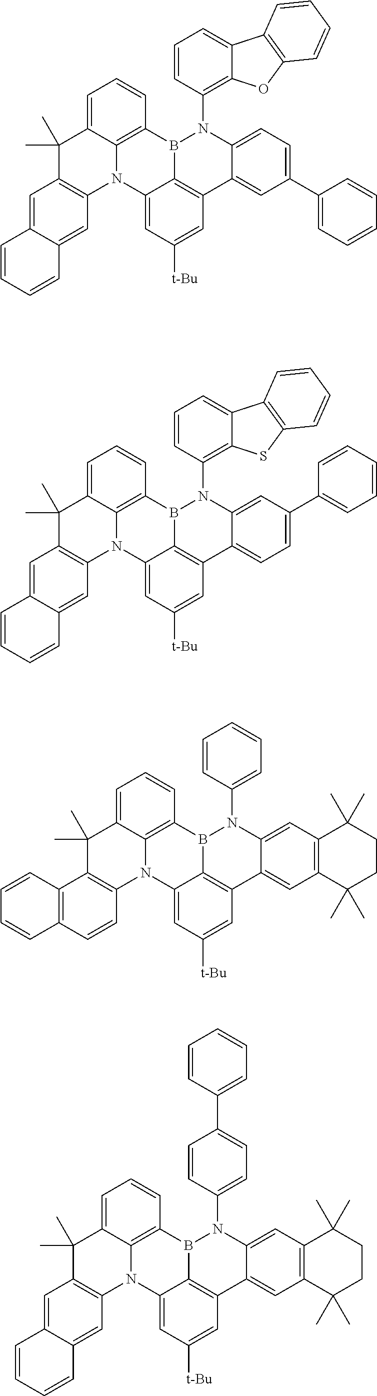 [SMILES: CC(C)(C)c1cc2c3c(c1)N1c4cc5ccccc5cc4C(C)(C)c4cccc(c41)B3N(c1cccc3c1oc1ccccc13)c1ccc(-c3ccccc3)cc1-2 ; CC(C)(C)c1cc2c3c(c1)N1c4cc5ccccc5cc4C(C)(C)c4cccc(c41)B3N(c1cccc3c1sc1ccccc13)c1cc(-c3ccccc3)ccc1-2 ; CC(C)(C)c1cc2c3c(c1)N1c4ccc5ccccc5c4C(C)(C)c4cccc(c41)B3N(c1ccccc1)c1cc3c(cc1-2)C(C)(C)CCC3(C)C ; CC(C)(C)c1cc2c3c(c1)N1c4cc5ccccc5cc4C(C)(C)c4cccc(c41)B3N(c1ccc(-c3ccccc3)cc1)c1cc3c(cc1-2)C(C)(C)CCC3(C)C] 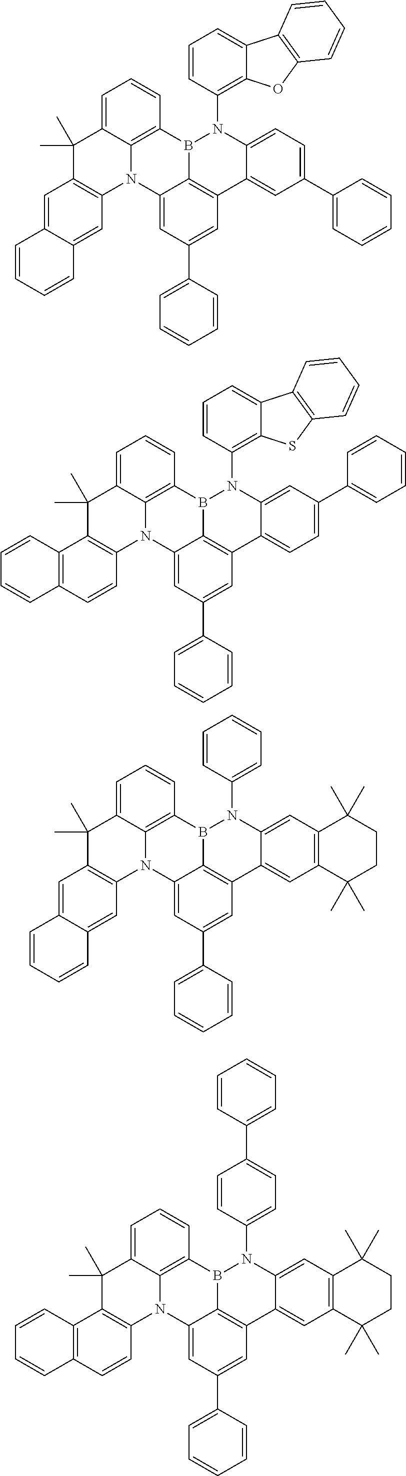 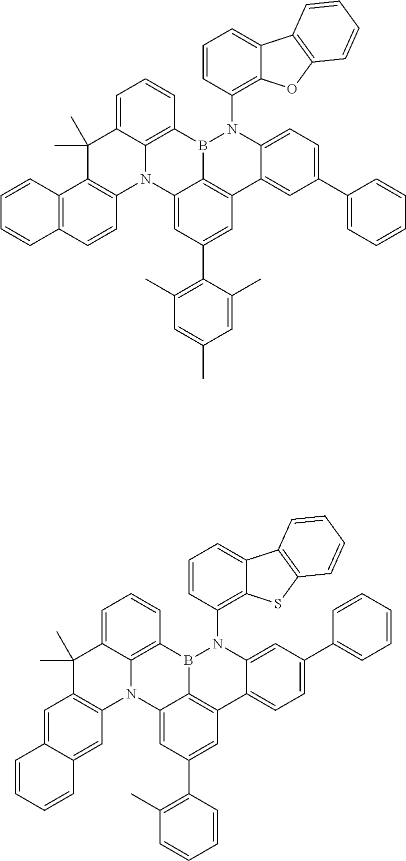 [SMILES: Cc1cc(C)c(-c2cc3c4c(c2)N2c5ccc6ccccc6c5C(C)(C)c5cccc(c52)B4N(c2cccc4c2oc2ccccc24)c2ccc(-c4ccccc4)cc2-3)c(C)c1 ; Cc1ccccc1-c1cc2c3c(c1)N1c4cc5ccccc5cc4C(C)(C)c4cccc(c41)B3N(c1cccc3c1sc1ccccc13)c1cc(-c3ccccc3)ccc1-2] 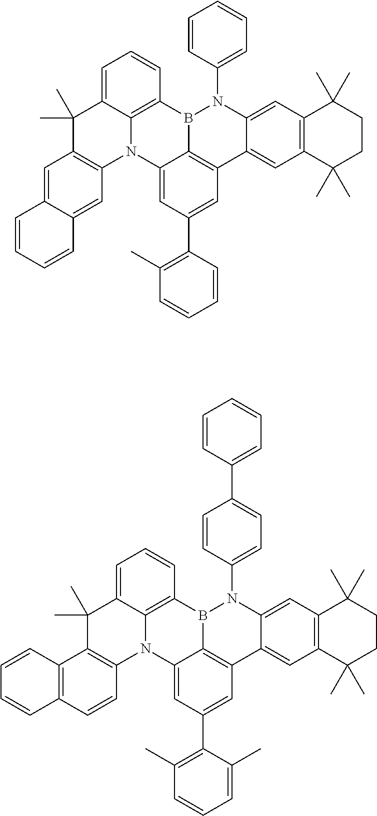 [SMILES: Cc1ccccc1-c1cc2c3c(c1)N1c4cc5ccccc5cc4C(C)(C)c4cccc(c41)B3N(c1ccccc1)c1cc3c(cc1-2)C(C)(C)CCC3(C)C ; Cc1cccc(C)c1-c1cc2c3c(c1)N1c4ccc5ccccc5c4C(C)(C)c4cccc(c41)B3N(c1ccc(-c3ccccc3)cc1)c1cc3c(cc1-2)C(C)(C)CCC3(C)C] 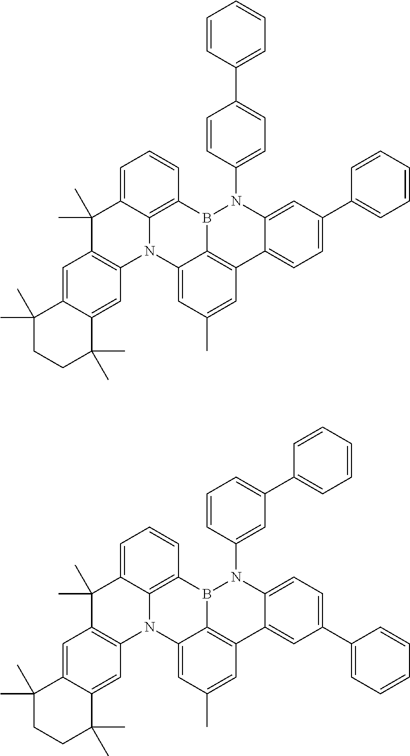 [SMILES: Cc1cc2c3c(c1)N1c4cc5c(cc4C(C)(C)c4cccc(c41)B3N(c1ccc(-c3ccccc3)cc1)c1cc(-c3ccccc3)ccc1-2)C(C)(C)CCC5(C)C ; Cc1cc2c3c(c1)N1c4cc5c(cc4C(C)(C)c4cccc(c41)B3N(c1cccc(-c3ccccc3)c1)c1ccc(-c3ccccc3)cc1-2)C(C)(C)CCC5(C)C] 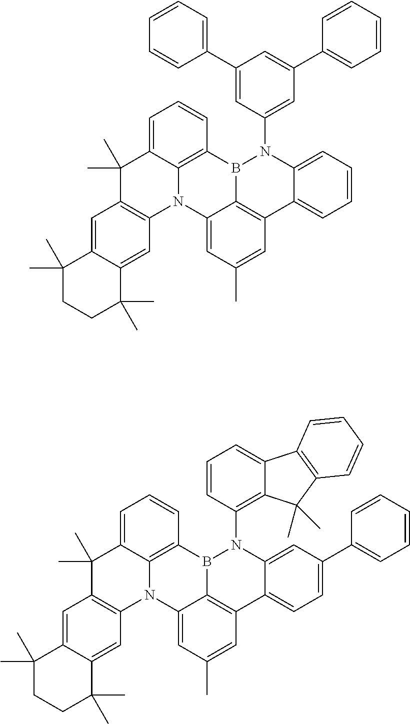 [SMILES: Cc1cc2c3c(c1)N1c4cc5c(cc4C(C)(C)c4cccc(c41)B3N(c1cc(-c3ccccc3)cc(-c3ccccc3)c1)c1ccccc1-2)C(C)(C)CCC5(C)C ; Cc1cc2c3c(c1)N1c4cc5c(cc4C(C)(C)c4cccc(c41)B3N(c1cccc3c1C(C)(C)c1ccccc1-3)c1cc(-c3ccccc3)ccc1-2)C(C)(C)CCC5(C)C] 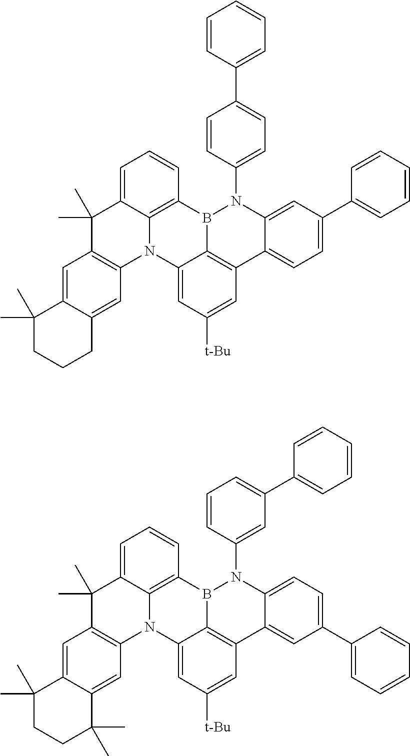 [SMILES: CC(C)(C)c1cc2c3c(c1)N1c4cc5c(cc4C(C)(C)c4cccc(c41)B3N(c1ccc(-c3ccccc3)cc1)c1cc(-c3ccccc3)ccc1-2)C(C)(C)CCC5 ; CC(C)(C)c1cc2c3c(c1)N1c4cc5c(cc4C(C)(C)c4cccc(c41)B3N(c1cccc(-c3ccccc3)c1)c1ccc(-c3ccccc3)cc1-2)C(C)(C)CCC5(C)C] 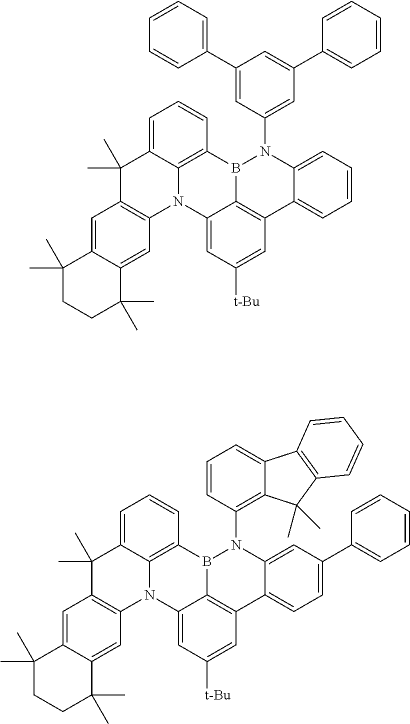 [SMILES: CC(C)(C)c1cc2c3c(c1)N1c4cc5c(cc4C(C)(C)c4cccc(c41)B3N(c1cc(-c3ccccc3)cc(-c3ccccc3)c1)c1ccccc1-2)C(C)(C)CCC5(C)C ; CC(C)(C)c1cc2c3c(c1)N1c4cc5c(cc4C(C)(C)c4cccc(c41)B3N(c1cccc3c1C(C)(C)c1ccccc1-3)c1cc(-c3ccccc3)ccc1-2)C(C)(C)CCC5(C)C] 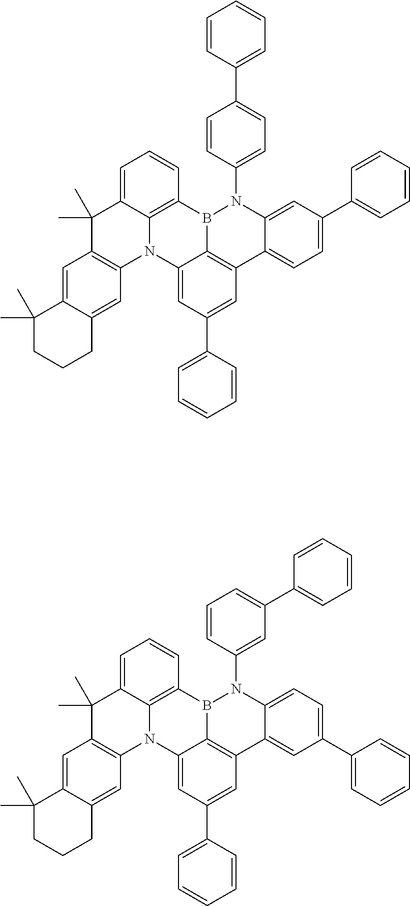 [SMILES: CC1(C)CCCc2cc3c(cc21)C(C)(C)c1cccc2c1N3c1cc(-c3ccccc3)cc3c1B2N(c1ccc(-c2ccccc2)cc1)c1cc(-c2ccccc2)ccc1-3 ; CC1(C)CCCc2cc3c(cc21)C(C)(C)c1cccc2c1N3c1cc(-c3ccccc3)cc3c1B2N(c1cccc(-c2ccccc2)c1)c1ccc(-c2ccccc2)cc1-3] 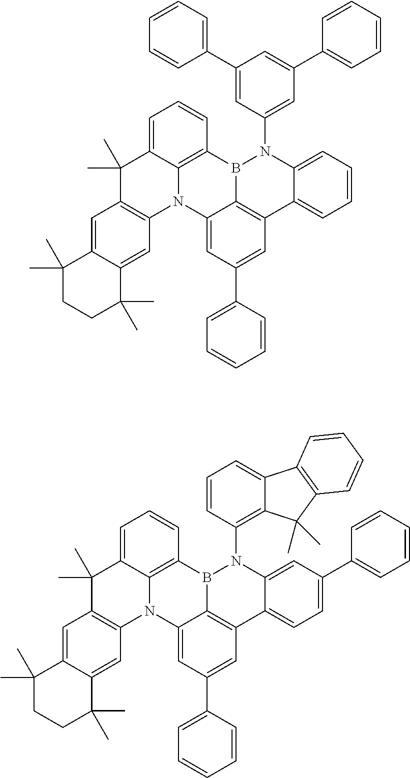 [SMILES: CC1(C)CCC(C)(C)c2cc3c(cc21)N1c2cc(-c4ccccc4)cc4c2B(c2cccc(c21)C3(C)C)N(c1cc(-c2ccccc2)cc(-c2ccccc2)c1)c1ccccc1-4 ; CC1(C)CCC(C)(C)c2cc3c(cc21)N1c2cc(-c4ccccc4)cc4c2B(c2cccc(c21)C3(C)C)N(c1cccc2c1C(C)(C)c1ccccc1-2)c1cc(-c2ccccc2)ccc1-4] 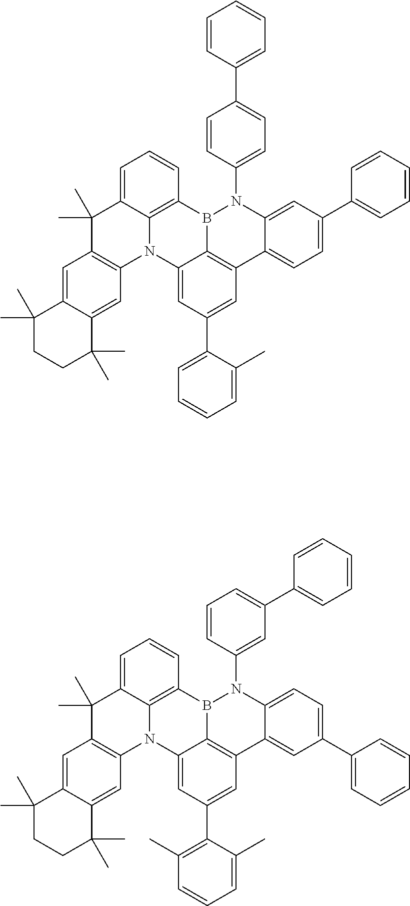 [SMILES: Cc1ccccc1-c1cc2c3c(c1)N1c4cc5c(cc4C(C)(C)c4cccc(c41)B3N(c1ccc(-c3ccccc3)cc1)c1cc(-c3ccccc3)ccc1-2)C(C)(C)CCC5(C)C ; Cc1cccc(C)c1-c1cc2c3c(c1)N1c4cc5c(cc4C(C)(C)c4cccc(c41)B3N(c1cccc(-c3ccccc3)c1)c1ccc(-c3ccccc3)cc1-2)C(C)(C)CCC5(C)C] 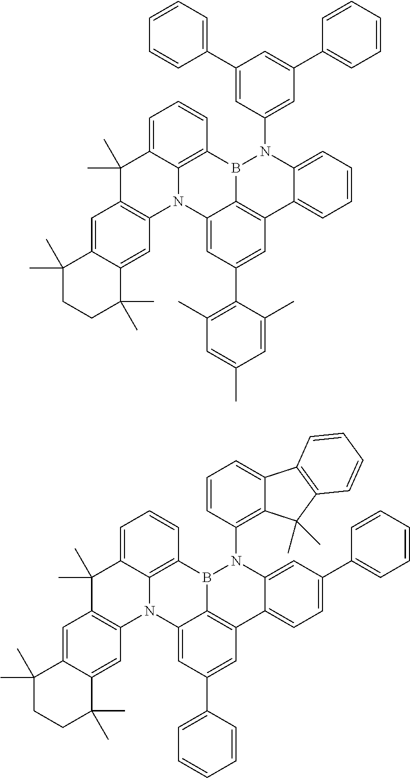 [SMILES: Cc1cc(C)c(-c2cc3c4c(c2)N2c5cc6c(cc5C(C)(C)c5cccc(c52)B4N(c2cc(-c4ccccc4)cc(-c4ccccc4)c2)c2ccccc2-3)C(C)(C)CCC6(C)C)c(C)c1 ; CC1(C)CCC(C)(C)c2cc3c(cc21)N1c2cc(-c4ccccc4)cc4c2B(c2cccc(c21)C3(C)C)N(c1cccc2c1C(C)(C)c1ccccc1-2)c1cc(-c2ccccc2)ccc1-4] 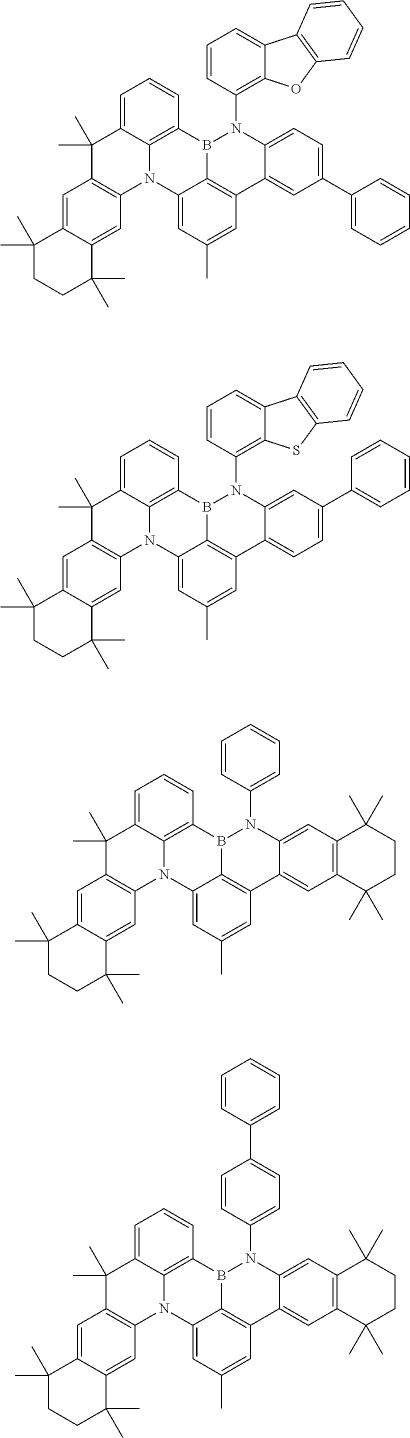 [SMILES: Cc1cc2c3c(c1)N1c4cc5c(cc4C(C)(C)c4cccc(c41)B3N(c1cccc3c1oc1ccccc13)c1ccc(-c3ccccc3)cc1-2)C(C)(C)CCC5(C)C ; Cc1cc2c3c(c1)N1c4cc5c(cc4C(C)(C)c4cccc(c41)B3N(c1cccc3c1sc1ccccc13)c1cc(-c3ccccc3)ccc1-2)C(C)(C)CCC5(C)C ; Cc1cc2c3c(c1)N1c4cc5c(cc4C(C)(C)c4cccc(c41)B3N(c1ccccc1)c1cc3c(cc1-2)C(C)(C)CCC3(C)C)C(C)(C)CCC5(C)C ; Cc1cc2c3c(c1)N1c4cc5c(cc4C(C)(C)c4cccc(c41)B3N(c1ccc(-c3ccccc3)cc1)c1cc3c(cc1-2)C(C)(C)CCC3(C)C)C(C)(C)CCC5(C)C] 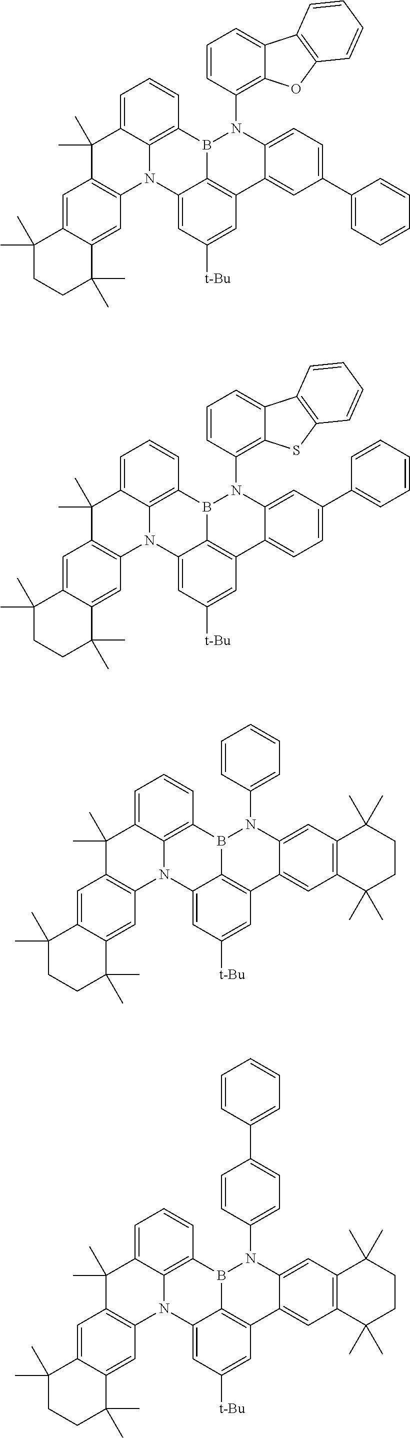 [SMILES: CC(C)(C)c1cc2c3c(c1)N1c4cc5c(cc4C(C)(C)c4cccc(c41)B3N(c1cccc3c1oc1ccccc13)c1ccc(-c3ccccc3)cc1-2)C(C)(C)CCC5(C)C ; CC(C)(C)c1cc2c3c(c1)N1c4cc5c(cc4C(C)(C)c4cccc(c41)B3N(c1cccc3c1sc1ccccc13)c1cc(-c3ccccc3)ccc1-2)C(C)(C)CCC5(C)C ; CC(C)(C)c1cc2c3c(c1)N1c4cc5c(cc4C(C)(C)c4cccc(c41)B3N(c1ccccc1)c1cc3c(cc1-2)C(C)(C)CCC3(C)C)C(C)(C)CCC5(C)C ; CC(C)(C)c1cc2c3c(c1)N1c4cc5c(cc4C(C)(C)c4cccc(c41)B3N(c1ccc(-c3ccccc3)cc1)c1cc3c(cc1-2)C(C)(C)CCC3(C)C)C(C)(C)CCC5(C)C] 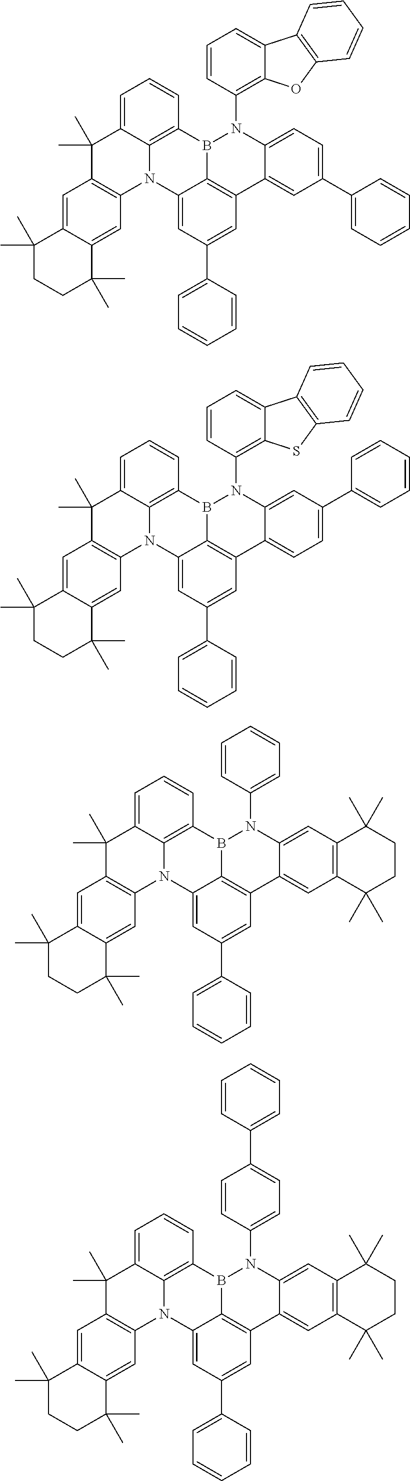 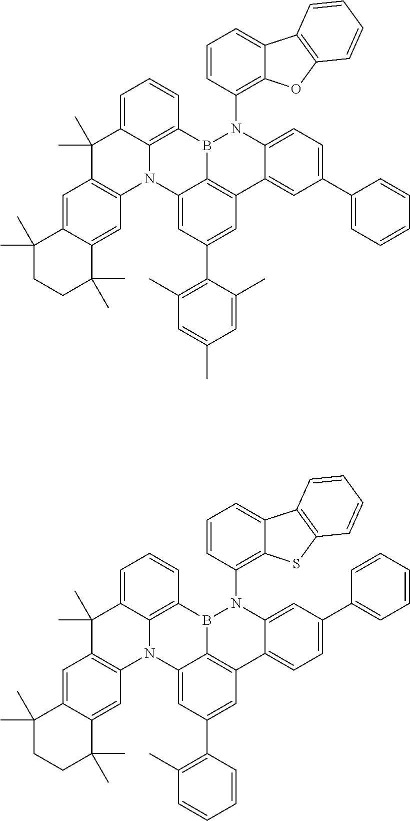 [SMILES: Cc1cc(C)c(-c2cc3c4c(c2)N2c5cc6c(cc5C(C)(C)c5cccc(c52)B4N(c2cccc4c2oc2ccccc24)c2ccc(-c4ccccc4)cc2-3)C(C)(C)CCC6(C)C)c(C)c1 ; Cc1ccccc1-c1cc2c3c(c1)N1c4cc5c(cc4C(C)(C)c4cccc(c41)B3N(c1cccc3c1sc1ccccc13)c1cc(-c3ccccc3)ccc1-2)C(C)(C)CCC5(C)C] 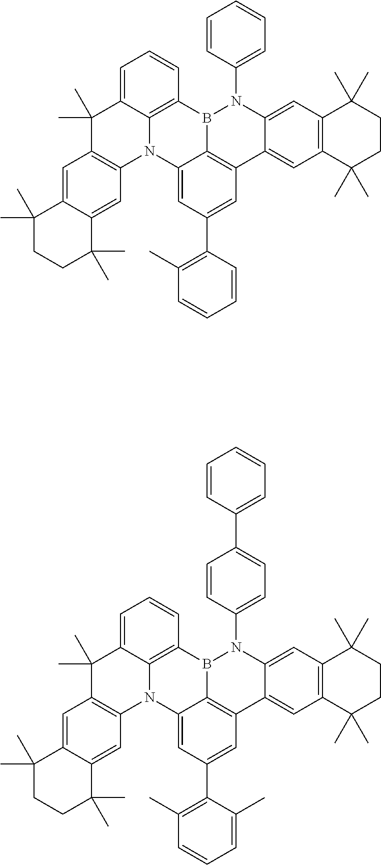 [SMILES: Cc1ccccc1-c1cc2c3c(c1)N1c4cc5c(cc4C(C)(C)c4cccc(c41)B3N(c1ccccc1)c1cc3c(cc1-2)C(C)(C)CCC3(C)C)C(C)(C)CCC5(C)C ; Cc1cccc(C)c1-c1cc2c3c(c1)N1c4cc5c(cc4C(C)(C)c4cccc(c41)B3N(c1ccc(-c3ccccc3)cc1)c1cc3c(cc1-2)C(C)(C)CCC3(C)C)C(C)(C)CCC5(C)C] 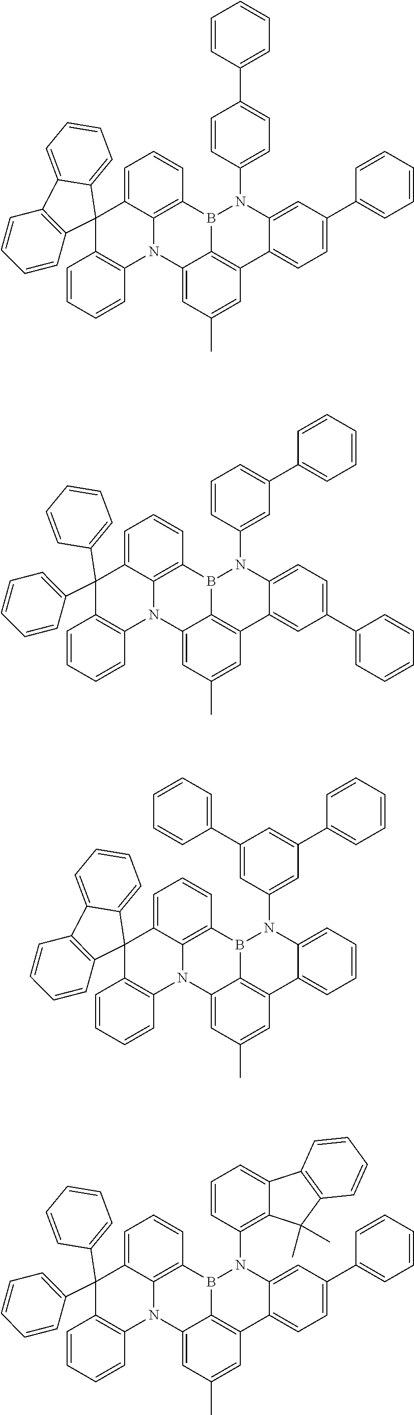 [SMILES: Cc1cc2c3c(c1)N1c4ccccc4C4(c5ccccc5-c5ccccc54)c4cccc(c41)B3N(c1ccc(-c3ccccc3)cc1)c1cc(-c3ccccc3)ccc1-2 ; Cc1cc2c3c(c1)N1c4ccccc4C(c4ccccc4)(c4ccccc4)c4cccc(c41)B3N(c1cccc(-c3ccccc3)c1)c1ccc(-c3ccccc3)cc1-2 ; Cc1cc2c3c(c1)N1c4ccccc4C4(c5ccccc5-c5ccccc54)c4cccc(c41)B3N(c1cc(-c3ccccc3)cc(-c3ccccc3)c1)c1ccccc1-2 ; Cc1cc2c3c(c1)N1c4ccccc4C(c4ccccc4)(c4ccccc4)c4cccc(c41)B3N(c1cccc3c1C(C)(C)c1ccccc1-3)c1cc(-c3ccccc3)ccc1-2] 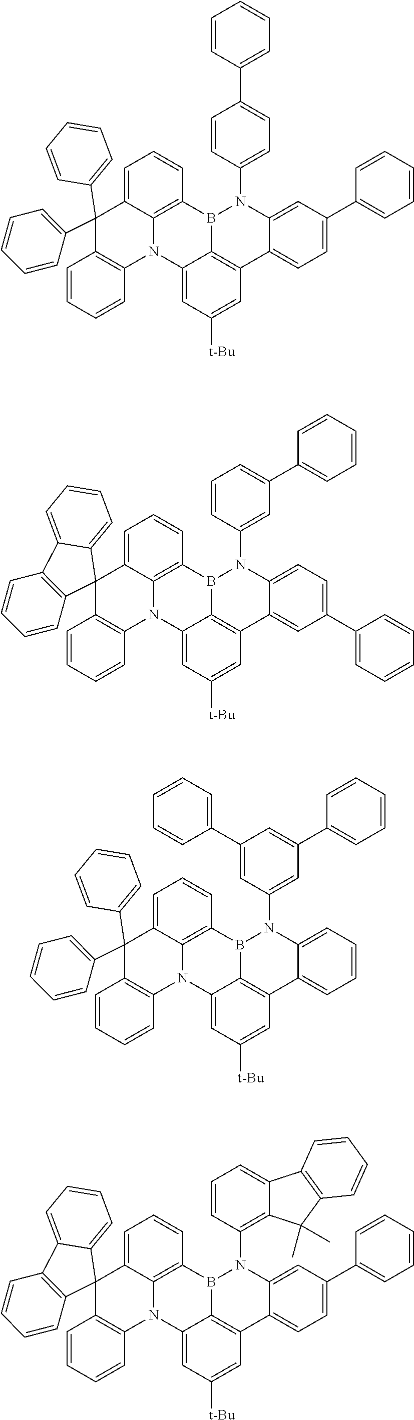 [SMILES: CC(C)(C)c1cc2c3c(c1)N1c4ccccc4C(c4ccccc4)(c4ccccc4)c4cccc(c41)B3N(c1ccc(-c3ccccc3)cc1)c1cc(-c3ccccc3)ccc1-2 ; CC(C)(C)c1cc2c3c(c1)N1c4ccccc4C4(c5ccccc5-c5ccccc54)c4cccc(c41)B3N(c1cccc(-c3ccccc3)c1)c1ccc(-c3ccccc3)cc1-2 ; CC(C)(C)c1cc2c3c(c1)N1c4ccccc4C(c4ccccc4)(c4ccccc4)c4cccc(c41)B3N(c1cc(-c3ccccc3)cc(-c3ccccc3)c1)c1ccccc1-2 ; CC(C)(C)c1cc2c3c(c1)N1c4ccccc4C4(c5ccccc5-c5ccccc54)c4cccc(c41)B3N(c1cccc3c1C(C)(C)c1ccccc1-3)c1cc(-c3ccccc3)ccc1-2] 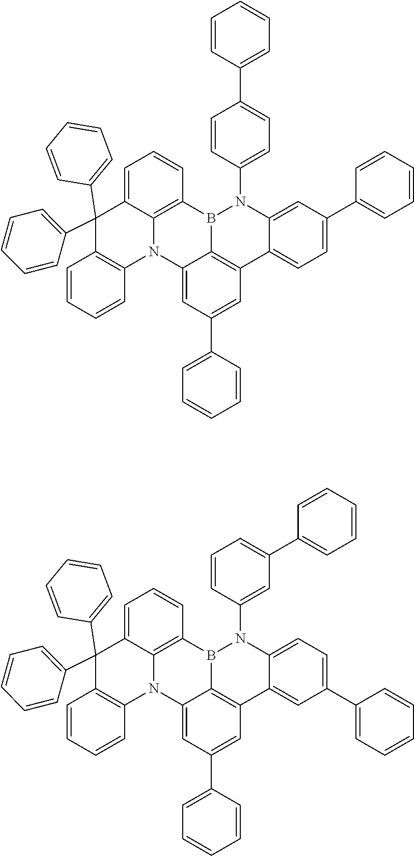 [SMILES: c1ccc(-c2ccc(N3B4c5cccc6c5N(c5ccccc5C6(c5ccccc5)c5ccccc5)c5cc(-c6ccccc6)cc(c54)-c4ccc(-c5ccccc5)cc43)cc2)cc1 ; c1ccc(-c2cccc(N3B4c5cccc6c5N(c5ccccc5C6(c5ccccc5)c5ccccc5)c5cc(-c6ccccc6)cc(c54)-c4cc(-c5ccccc5)ccc43)c2)cc1] 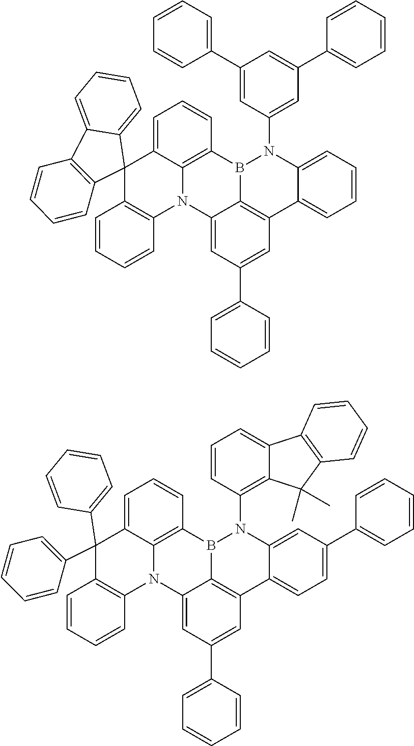 [SMILES: c1ccc(-c2cc(-c3ccccc3)cc(N3B4c5cccc6c5N(c5ccccc5C65c6ccccc6-c6ccccc65)c5cc(-c6ccccc6)cc(c54)-c4ccccc43)c2)cc1 ; CC1(C)c2ccccc2-c2cccc(N3B4c5cccc6c5N(c5ccccc5C6(c5ccccc5)c5ccccc5)c5cc(-c6ccccc6)cc(c54)-c4ccc(-c5ccccc5)cc43)c21] 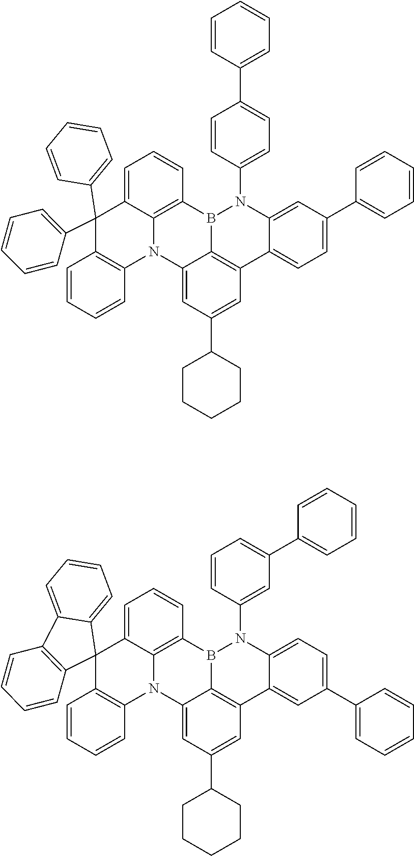 [SMILES: c1ccc(-c2ccc(N3B4c5cccc6c5N(c5ccccc5C6(c5ccccc5)c5ccccc5)c5cc(C6CCCCC6)cc(c54)-c4ccc(-c5ccccc5)cc43)cc2)cc1 ; c1ccc(-c2cccc(N3B4c5cccc6c5N(c5ccccc5C65c6ccccc6-c6ccccc65)c5cc(C6CCCCC6)cc(c54)-c4cc(-c5ccccc5)ccc43)c2)cc1] 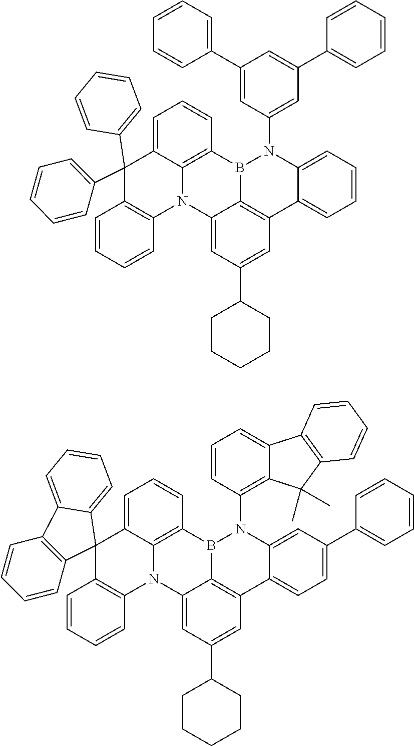 [SMILES: c1ccc(-c2cc(-c3ccccc3)cc(N3B4c5cccc6c5N(c5ccccc5C6(c5ccccc5)c5ccccc5)c5cc(C6CCCCC6)cc(c54)-c4ccccc43)c2)cc1 ; CC1(C)c2ccccc2-c2cccc(N3B4c5cccc6c5N(c5ccccc5C65c6ccccc6-c6ccccc65)c5cc(C6CCCCC6)cc(c54)-c4ccc(-c5ccccc5)cc43)c21] 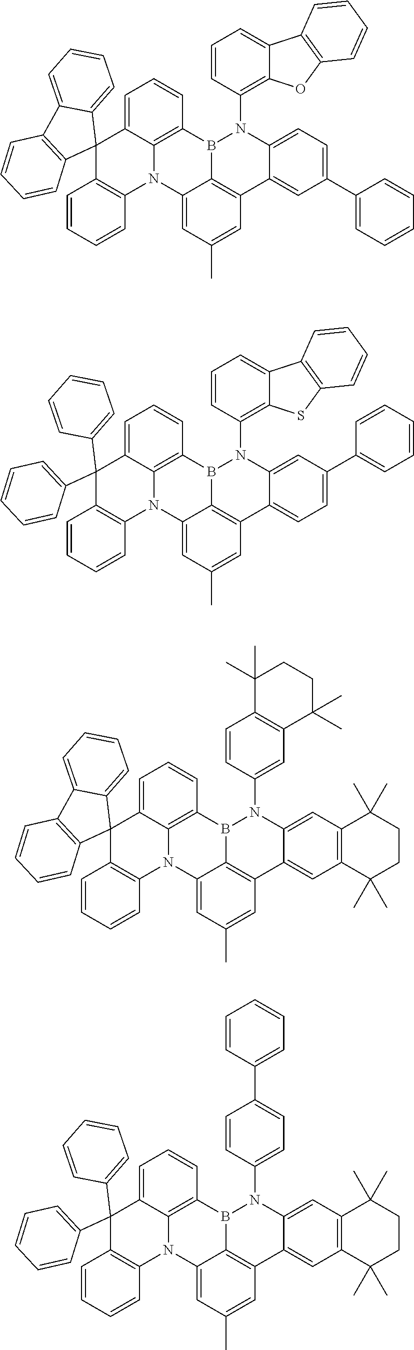 [SMILES: Cc1cc2c3c(c1)N1c4ccccc4C4(c5ccccc5-c5ccccc54)c4cccc(c41)B3N(c1cccc3c1oc1ccccc13)c1ccc(-c3ccccc3)cc1-2 ; Cc1cc2c3c(c1)N1c4ccccc4C(c4ccccc4)(c4ccccc4)c4cccc(c41)B3N(c1cccc3c1sc1ccccc13)c1cc(-c3ccccc3)ccc1-2 ; Cc1cc2c3c(c1)N1c4ccccc4C4(c5ccccc5-c5ccccc54)c4cccc(c41)B3N(c1ccc3c(c1)C(C)(C)CCC3(C)C)c1cc3c(cc1-2)C(C)(C)CCC3(C)C ; Cc1cc2c3c(c1)N1c4ccccc4C(c4ccccc4)(c4ccccc4)c4cccc(c41)B3N(c1ccc(-c3ccccc3)cc1)c1cc3c(cc1-2)C(C)(C)CCC3(C)C] 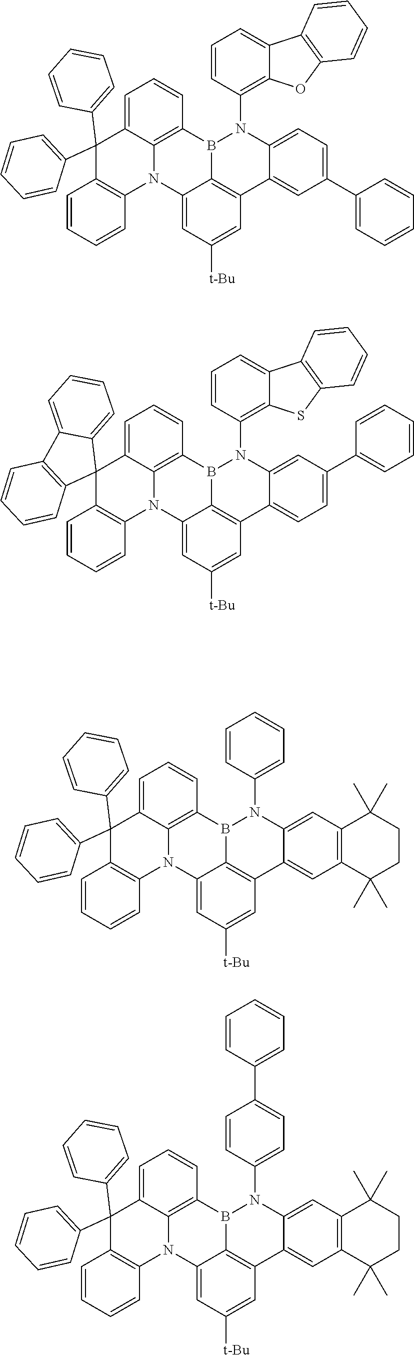 [SMILES: CC(C)(C)c1cc2c3c(c1)N1c4ccccc4C(c4ccccc4)(c4ccccc4)c4cccc(c41)B3N(c1cccc3c1oc1ccccc13)c1ccc(-c3ccccc3)cc1-2 ; CC(C)(C)c1cc2c3c(c1)N1c4ccccc4C4(c5ccccc5-c5ccccc54)c4cccc(c41)B3N(c1cccc3c1sc1ccccc13)c1cc(-c3ccccc3)ccc1-2 ; CC(C)(C)c1cc2c3c(c1)N1c4ccccc4C(c4ccccc4)(c4ccccc4)c4cccc(c41)B3N(c1ccccc1)c1cc3c(cc1-2)C(C)(C)CCC3(C)C ; CC(C)(C)c1cc2c3c(c1)N1c4ccccc4C(c4ccccc4)(c4ccccc4)c4cccc(c41)B3N(c1ccc(-c3ccccc3)cc1)c1cc3c(cc1-2)C(C)(C)CCC3(C)C] 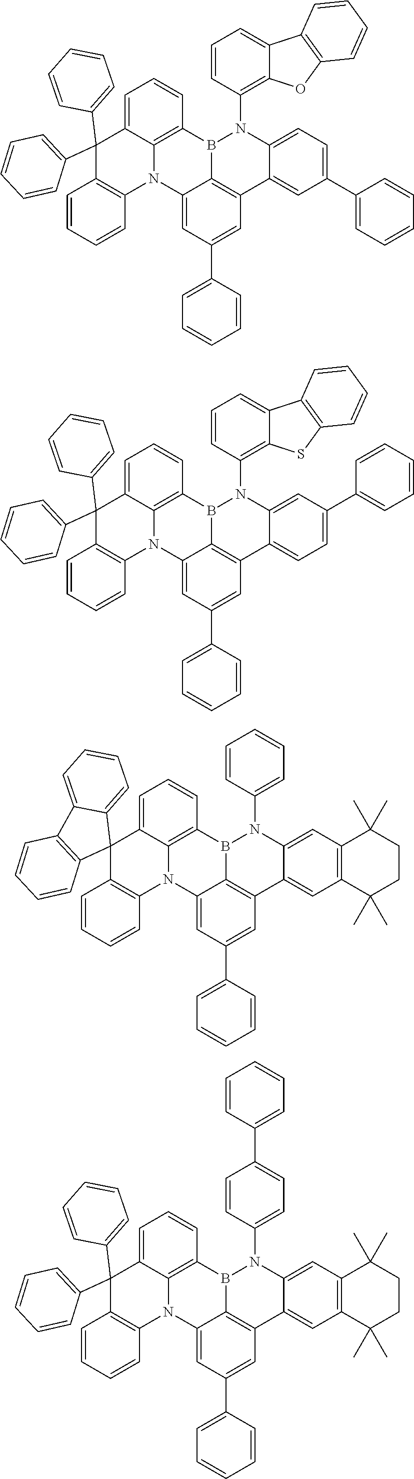 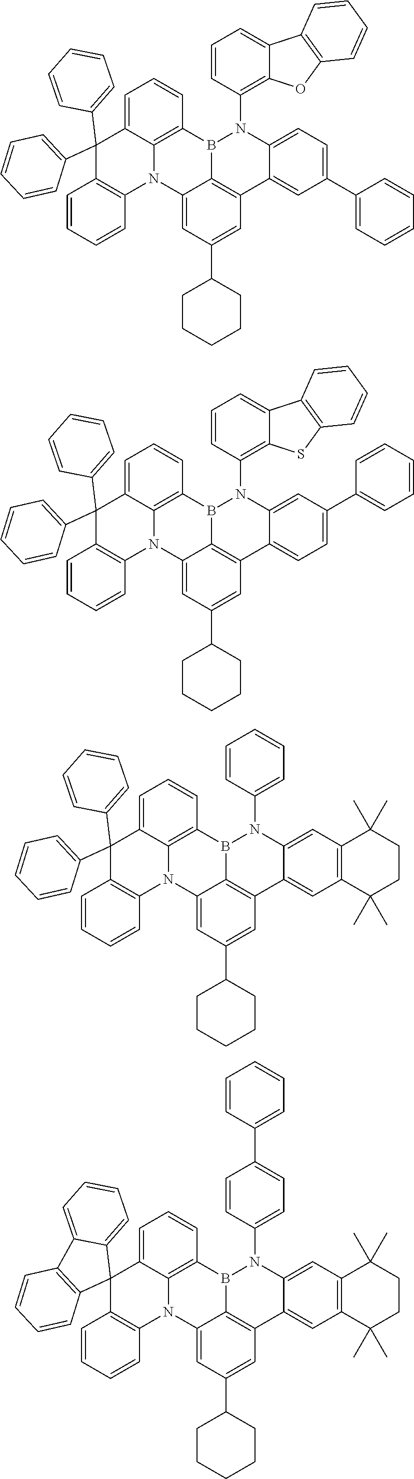 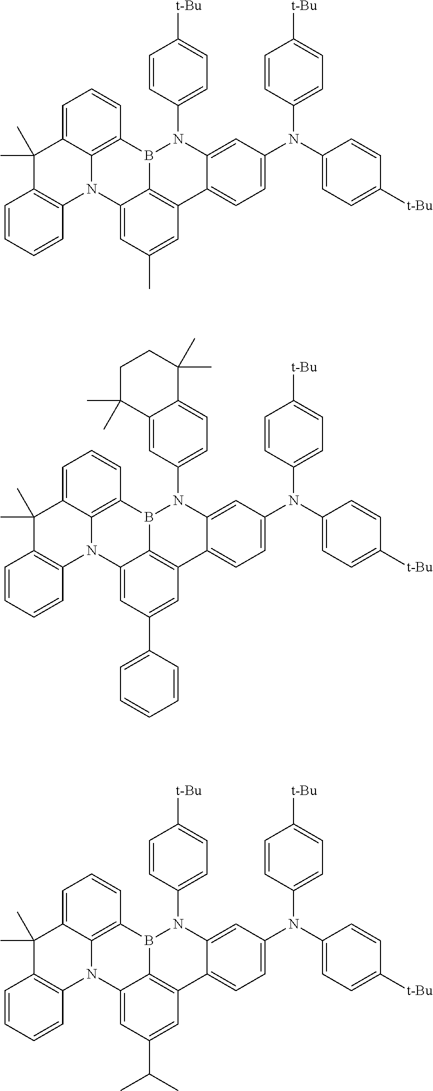 [SMILES: Cc1cc2c3c(c1)N1c4ccccc4C(C)(C)c4cccc(c41)B3N(c1ccc(C(C)(C)C)cc1)c1cc(N(c3ccc(C(C)(C)C)cc3)c3ccc(C(C)(C)C)cc3)ccc1-2 ; CC(C)(C)c1ccc(N(c2ccc(C(C)(C)C)cc2)c2ccc3c(c2)N(c2ccc4c(c2)C(C)(C)CCC4(C)C)B2c4cccc5c4N(c4ccccc4C5(C)C)c4cc(-c5ccccc5)cc-3c42)cc1 ; CC(C)c1cc2c3c(c1)N1c4ccccc4C(C)(C)c4cccc(c41)B3N(c1ccc(C(C)(C)C)cc1)c1cc(N(c3ccc(C(C)(C)C)cc3)c3ccc(C(C)(C)C)cc3)ccc1-2] 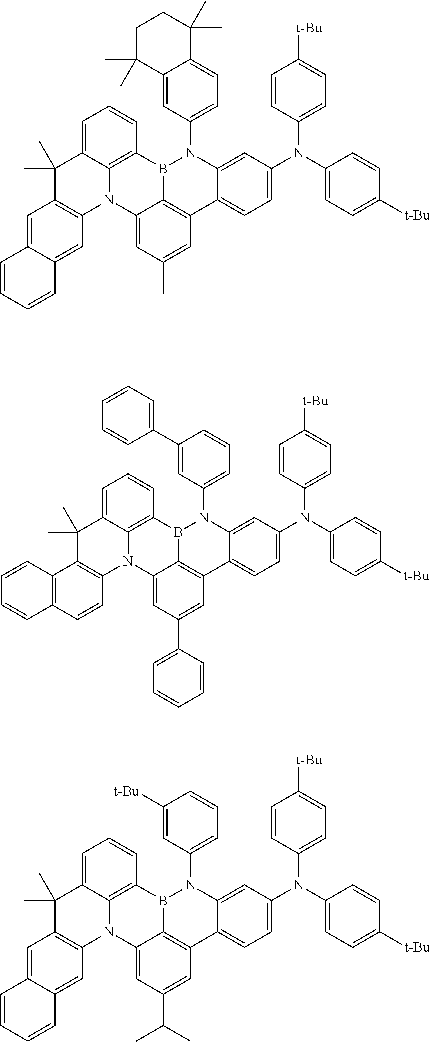 [SMILES: Cc1cc2c3c(c1)N1c4cc5ccccc5cc4C(C)(C)c4cccc(c41)B3N(c1ccc3c(c1)C(C)(C)CCC3(C)C)c1cc(N(c3ccc(C(C)(C)C)cc3)c3ccc(C(C)(C)C)cc3)ccc1-2 ; CC(C)(C)c1ccc(N(c2ccc(C(C)(C)C)cc2)c2ccc3c(c2)N(c2cccc(-c4ccccc4)c2)B2c4cccc5c4N(c4cc(-c6ccccc6)cc-3c42)c2ccc3ccccc3c2C5(C)C)cc1 ; CC(C)c1cc2c3c(c1)N1c4cc5ccccc5cc4C(C)(C)c4cccc(c41)B3N(c1cccc(C(C)(C)C)c1)c1cc(N(c3ccc(C(C)(C)C)cc3)c3ccc(C(C)(C)C)cc3)ccc1-2] 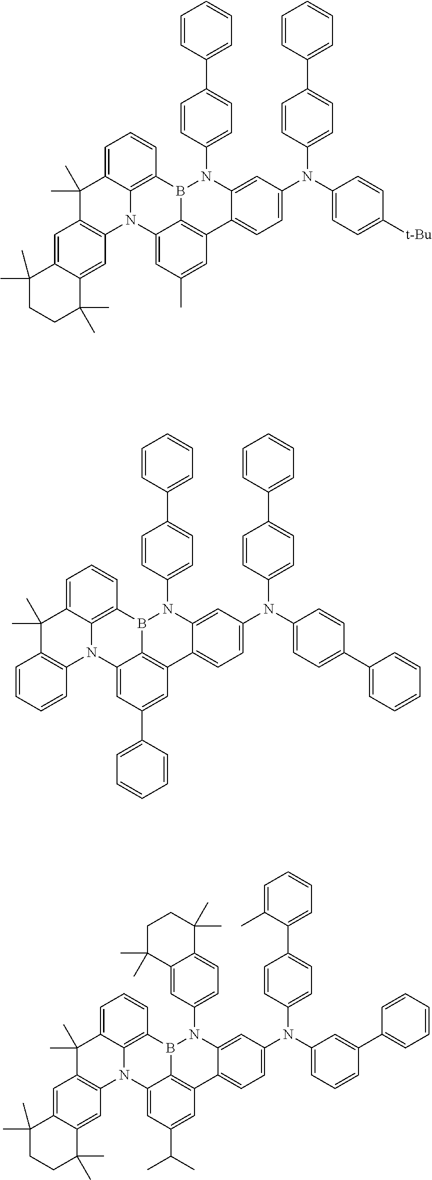 [SMILES: Cc1cc2c3c(c1)N1c4cc5c(cc4C(C)(C)c4cccc(c41)B3N(c1ccc(-c3ccccc3)cc1)c1cc(N(c3ccc(-c4ccccc4)cc3)c3ccc(C(C)(C)C)cc3)ccc1-2)C(C)(C)CCC5(C)C ; CC1(C)c2ccccc2N2c3cc(-c4ccccc4)cc4c3B(c3cccc1c32)N(c1ccc(-c2ccccc2)cc1)c1cc(N(c2ccc(-c3ccccc3)cc2)c2ccc(-c3ccccc3)cc2)ccc1-4 ; Cc1ccccc1-c1ccc(N(c2cccc(-c3ccccc3)c2)c2ccc3c(c2)N(c2ccc4c(c2)C(C)(C)CCC4(C)C)B2c4cccc5c4N(c4cc6c(cc4C5(C)C)C(C)(C)CCC6(C)C)c4cc(C(C)C)cc-3c42)cc1] 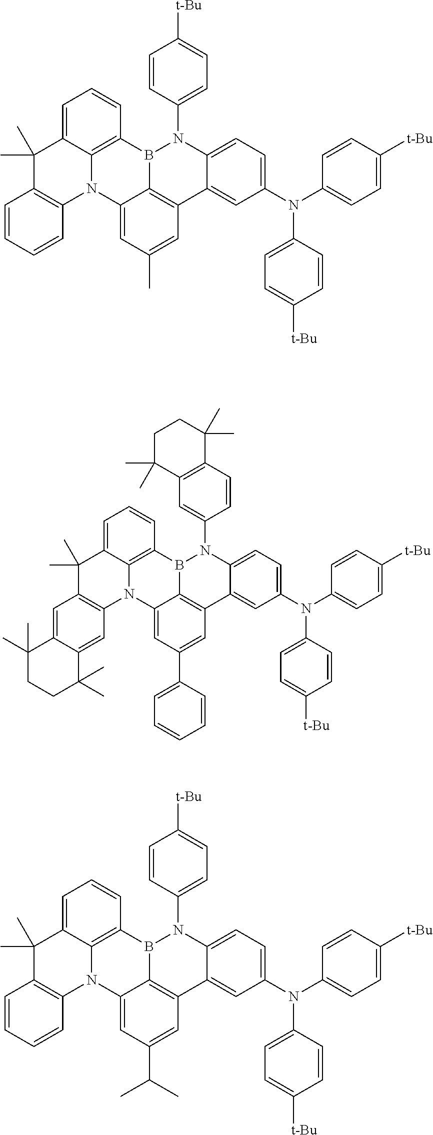 [SMILES: Cc1cc2c3c(c1)N1c4ccccc4C(C)(C)c4cccc(c41)B3N(c1ccc(C(C)(C)C)cc1)c1ccc(N(c3ccc(C(C)(C)C)cc3)c3ccc(C(C)(C)C)cc3)cc1-2 ; CC(C)(C)c1ccc(N(c2ccc(C(C)(C)C)cc2)c2ccc3c(c2)-c2cc(-c4ccccc4)cc4c2B(c2cccc5c2N4c2cc4c(cc2C5(C)C)C(C)(C)CCC4(C)C)N3c2ccc3c(c2)C(C)(C)CCC3(C)C)cc1 ; CC(C)c1cc2c3c(c1)N1c4ccccc4C(C)(C)c4cccc(c41)B3N(c1ccc(C(C)(C)C)cc1)c1ccc(N(c3ccc(C(C)(C)C)cc3)c3ccc(C(C)(C)C)cc3)cc1-2] 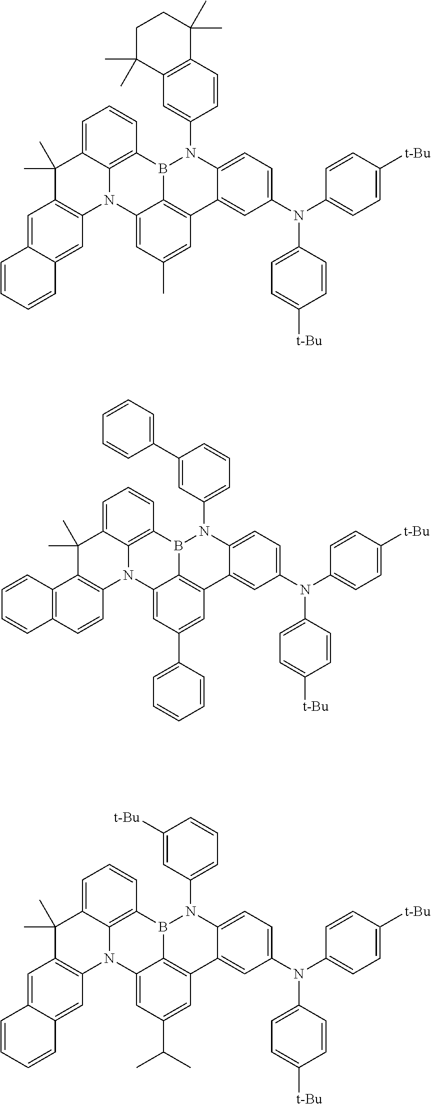 [SMILES: Cc1cc2c3c(c1)N1c4cc5ccccc5cc4C(C)(C)c4cccc(c41)B3N(c1ccc3c(c1)C(C)(C)CCC3(C)C)c1ccc(N(c3ccc(C(C)(C)C)cc3)c3ccc(C(C)(C)C)cc3)cc1-2 ; CC(C)(C)c1ccc(N(c2ccc(C(C)(C)C)cc2)c2ccc3c(c2)-c2cc(-c4ccccc4)cc4c2B(c2cccc5c2N4c2ccc4ccccc4c2C5(C)C)N3c2cccc(-c3ccccc3)c2)cc1 ; CC(C)c1cc2c3c(c1)N1c4cc5ccccc5cc4C(C)(C)c4cccc(c41)B3N(c1cccc(C(C)(C)C)c1)c1ccc(N(c3ccc(C(C)(C)C)cc3)c3ccc(C(C)(C)C)cc3)cc1-2] 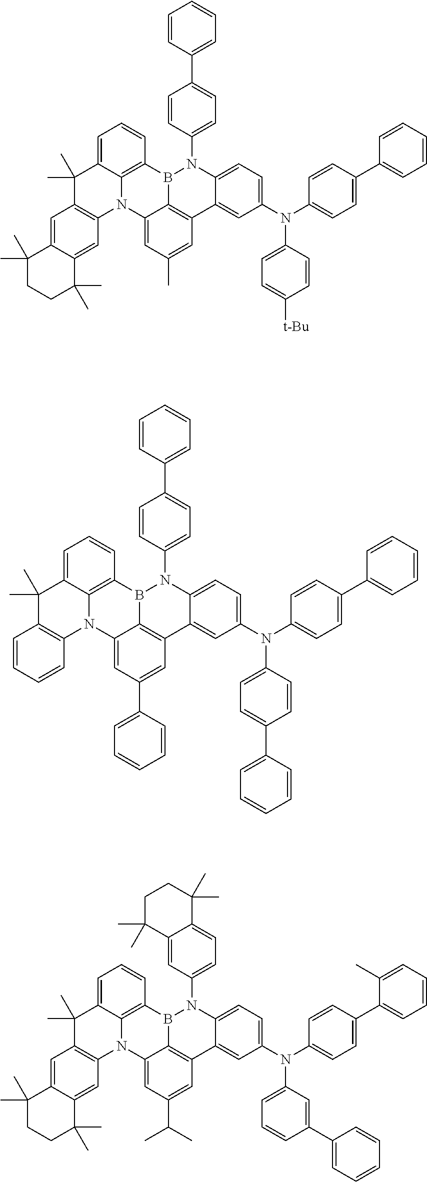 [SMILES: Cc1cc2c3c(c1)N1c4cc5c(cc4C(C)(C)c4cccc(c41)B3N(c1ccc(-c3ccccc3)cc1)c1ccc(N(c3ccc(-c4ccccc4)cc3)c3ccc(C(C)(C)C)cc3)cc1-2)C(C)(C)CCC5(C)C ; CC1(C)c2ccccc2N2c3cc(-c4ccccc4)cc4c3B(c3cccc1c32)N(c1ccc(-c2ccccc2)cc1)c1ccc(N(c2ccc(-c3ccccc3)cc2)c2ccc(-c3ccccc3)cc2)cc1-4 ; Cc1ccccc1-c1ccc(N(c2cccc(-c3ccccc3)c2)c2ccc3c(c2)-c2cc(C(C)C)cc4c2B(c2cccc5c2N4c2cc4c(cc2C5(C)C)C(C)(C)CCC4(C)C)N3c2ccc3c(c2)C(C)(C)CCC3(C)C)cc1] 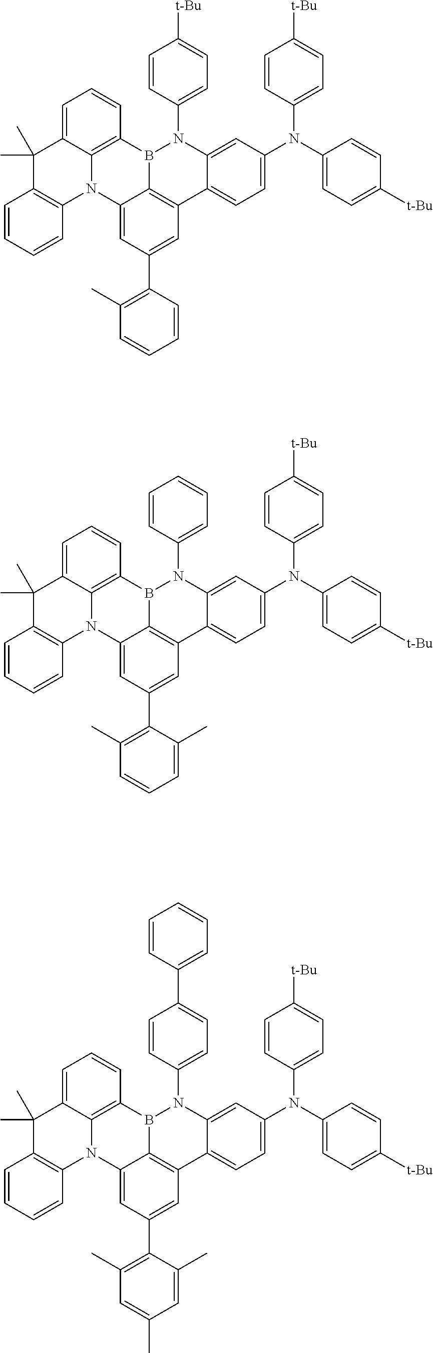 [SMILES: Cc1ccccc1-c1cc2c3c(c1)N1c4ccccc4C(C)(C)c4cccc(c41)B3N(c1ccc(C(C)(C)C)cc1)c1cc(N(c3ccc(C(C)(C)C)cc3)c3ccc(C(C)(C)C)cc3)ccc1-2 ; Cc1cccc(C)c1-c1cc2c3c(c1)N1c4ccccc4C(C)(C)c4cccc(c41)B3N(c1ccccc1)c1cc(N(c3ccc(C(C)(C)C)cc3)c3ccc(C(C)(C)C)cc3)ccc1-2 ; Cc1cc(C)c(-c2cc3c4c(c2)N2c5ccccc5C(C)(C)c5cccc(c52)B4N(c2ccc(-c4ccccc4)cc2)c2cc(N(c4ccc(C(C)(C)C)cc4)c4ccc(C(C)(C)C)cc4)ccc2-3)c(C)c1] 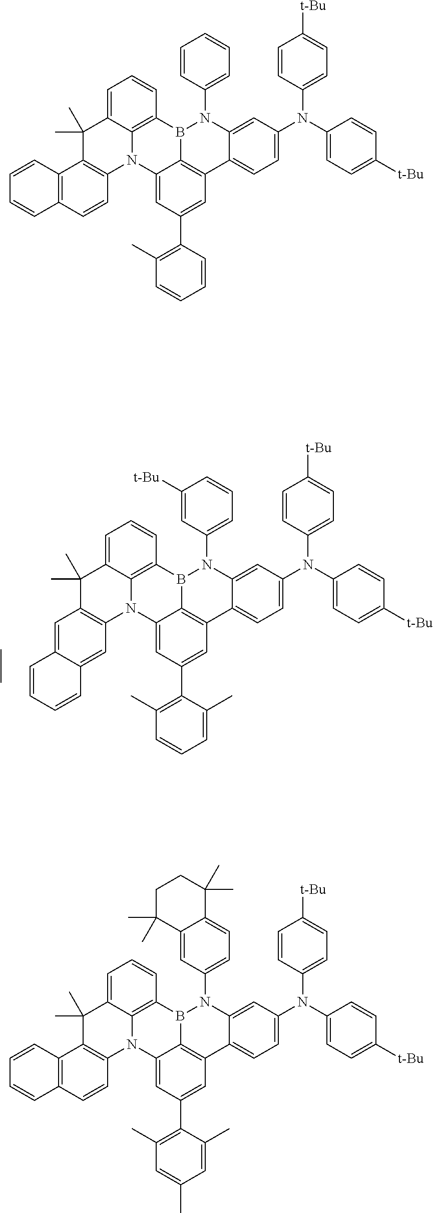 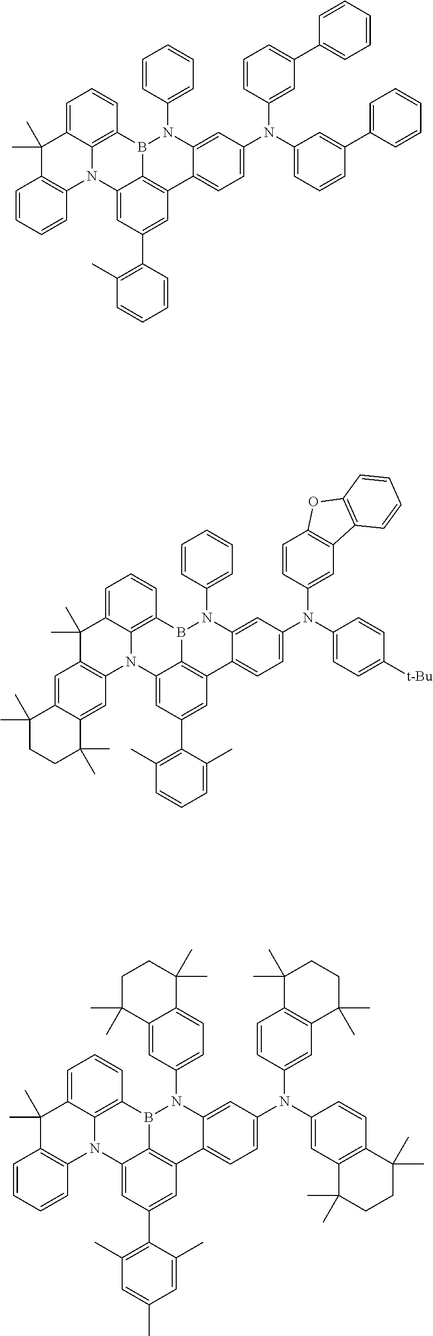 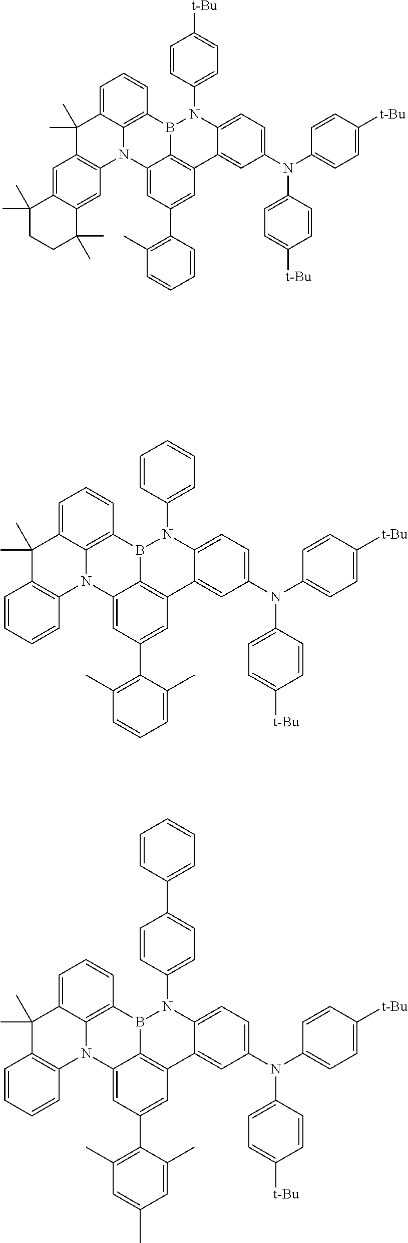 [SMILES: Cc1ccccc1-c1cc2c3c(c1)N1c4cc5c(cc4C(C)(C)c4cccc(c41)B3N(c1ccc(C(C)(C)C)cc1)c1ccc(N(c3ccc(C(C)(C)C)cc3)c3ccc(C(C)(C)C)cc3)cc1-2)C(C)(C)CCC5(C)C ; Cc1cccc(C)c1-c1cc2c3c(c1)N1c4ccccc4C(C)(C)c4cccc(c41)B3N(c1ccccc1)c1ccc(N(c3ccc(C(C)(C)C)cc3)c3ccc(C(C)(C)C)cc3)cc1-2 ; Cc1cc(C)c(-c2cc3c4c(c2)N2c5ccccc5C(C)(C)c5cccc(c52)B4N(c2ccc(-c4ccccc4)cc2)c2ccc(N(c4ccc(C(C)(C)C)cc4)c4ccc(C(C)(C)C)cc4)cc2-3)c(C)c1] 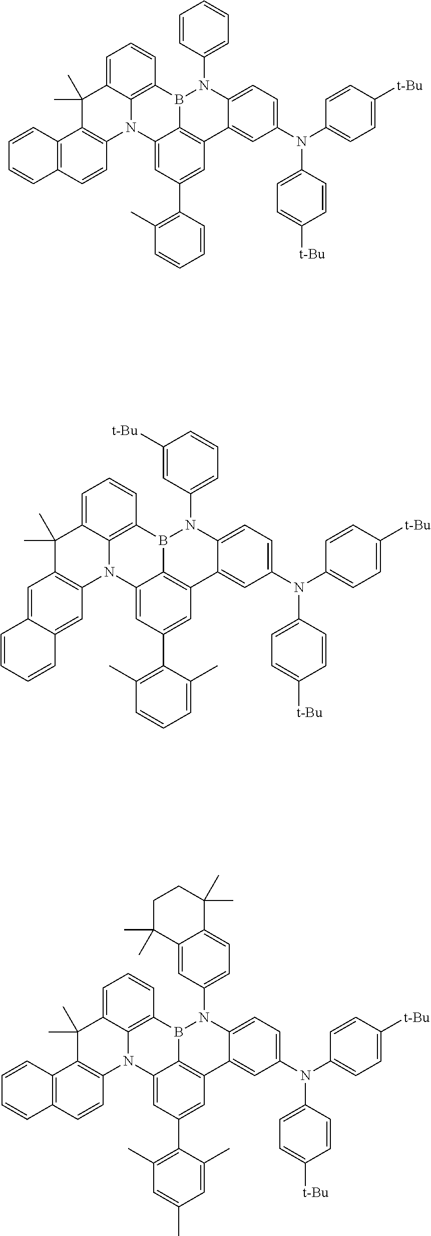 [SMILES: Cc1ccccc1-c1cc2c3c(c1)N1c4ccc5ccccc5c4C(C)(C)c4cccc(c41)B3N(c1ccccc1)c1ccc(N(c3ccc(C(C)(C)C)cc3)c3ccc(C(C)(C)C)cc3)cc1-2 ; Cc1cccc(C)c1-c1cc2c3c(c1)N1c4cc5ccccc5cc4C(C)(C)c4cccc(c41)B3N(c1cccc(C(C)(C)C)c1)c1ccc(N(c3ccc(C(C)(C)C)cc3)c3ccc(C(C)(C)C)cc3)cc1-2 ; Cc1cc(C)c(-c2cc3c4c(c2)N2c5ccc6ccccc6c5C(C)(C)c5cccc(c52)B4N(c2ccc4c(c2)C(C)(C)CCC4(C)C)c2ccc(N(c4ccc(C(C)(C)C)cc4)c4ccc(C(C)(C)C)cc4)cc2-3)c(C)c1] 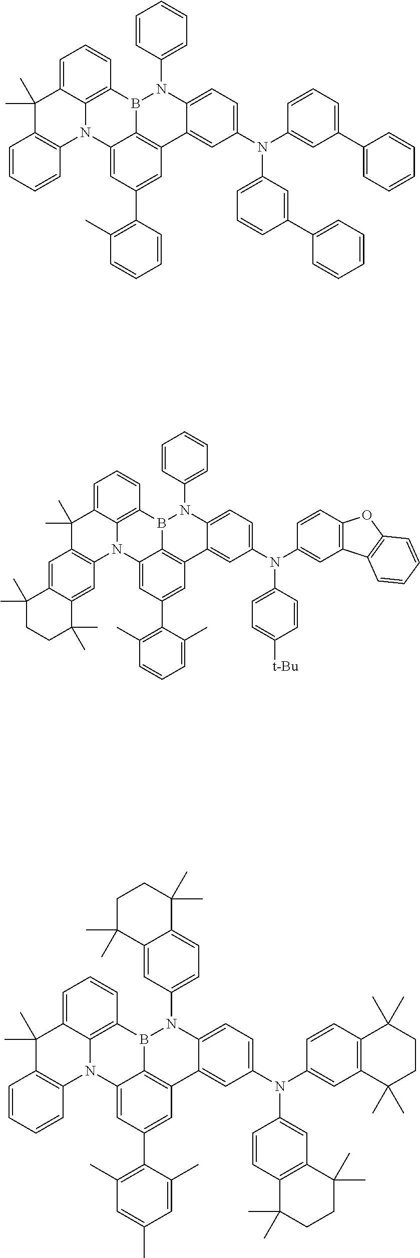 [SMILES: Cc1ccccc1-c1cc2c3c(c1)N1c4ccccc4C(C)(C)c4cccc(c41)B3N(c1ccccc1)c1ccc(N(c3cccc(-c4ccccc4)c3)c3cccc(-c4ccccc4)c3)cc1-2 ; Cc1cccc(C)c1-c1cc2c3c(c1)N1c4cc5c(cc4C(C)(C)c4cccc(c41)B3N(c1ccccc1)c1ccc(N(c3ccc(C(C)(C)C)cc3)c3ccc4oc6ccccc6c4c3)cc1-2)C(C)(C)CCC5(C)C ; Cc1cc(C)c(-c2cc3c4c(c2)N2c5ccccc5C(C)(C)c5cccc(c52)B4N(c2ccc4c(c2)C(C)(C)CCC4(C)C)c2ccc(N(c4ccc5c(c4)C(C)(C)CCC5(C)C)c4ccc5c(c4)C(C)(C)CCC5(C)C)cc2-3)c(C)c1] 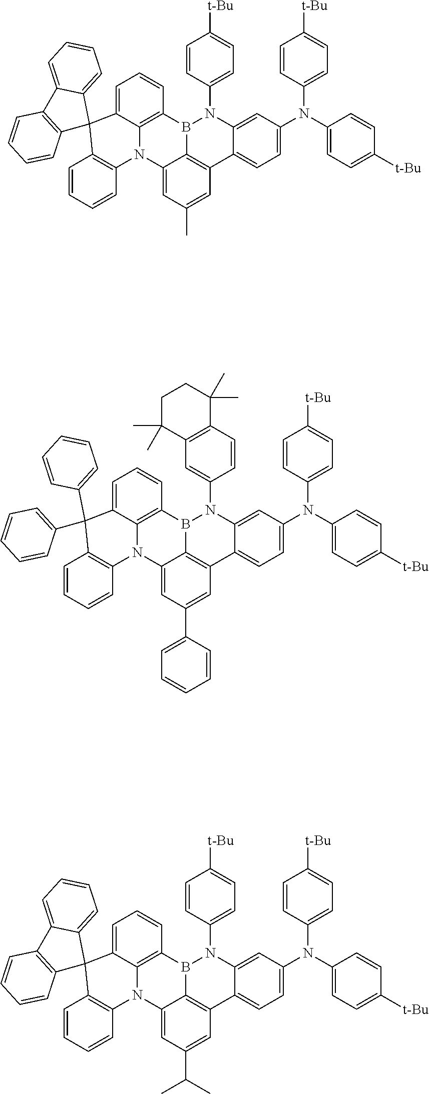 [SMILES: Cc1cc2c3c(c1)N1c4ccccc4C4(c5ccccc5-c5ccccc54)c4cccc(c41)B3N(c1ccc(C(C)(C)C)cc1)c1cc(N(c3ccc(C(C)(C)C)cc3)c3ccc(C(C)(C)C)cc3)ccc1-2 ; CC(C)(C)c1ccc(N(c2ccc(C(C)(C)C)cc2)c2ccc3c(c2)N(c2ccc4c(c2)C(C)(C)CCC4(C)C)B2c4cccc5c4N(c4ccccc4C5(c4ccccc4)c4ccccc4)c4cc(-c5ccccc5)cc-3c42)cc1 ; CC(C)c1cc2c3c(c1)N1c4ccccc4C4(c5ccccc5-c5ccccc54)c4cccc(c41)B3N(c1ccc(C(C)(C)C)cc1)c1cc(N(c3ccc(C(C)(C)C)cc3)c3ccc(C(C)(C)C)cc3)ccc1-2] 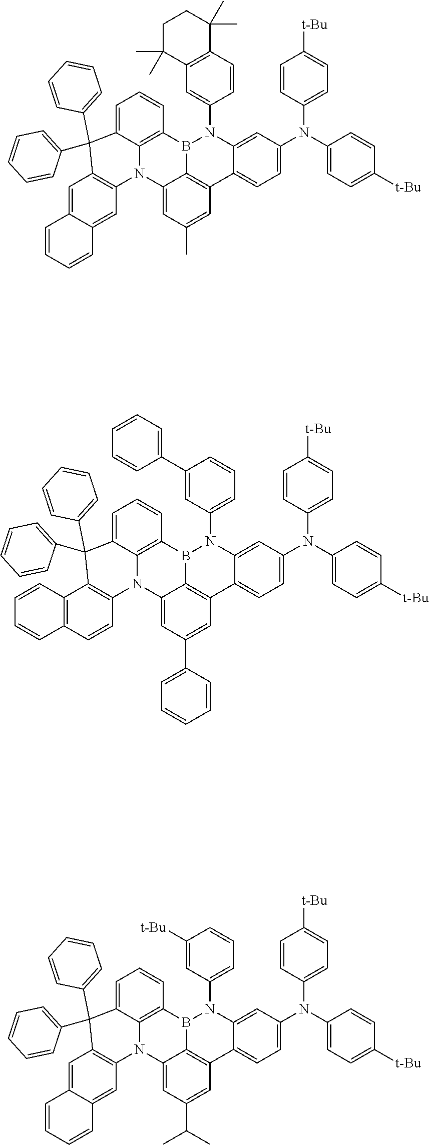 [SMILES: Cc1cc2c3c(c1)N1c4cc5ccccc5cc4C(c4ccccc4)(c4ccccc4)c4cccc(c41)B3N(c1ccc3c(c1)C(C)(C)CCC3(C)C)c1cc(N(c3ccc(C(C)(C)C)cc3)c3ccc(C(C)(C)C)cc3)ccc1-2 ; CC(C)(C)c1ccc(N(c2ccc(C(C)(C)C)cc2)c2ccc3c(c2)N(c2cccc(-c4ccccc4)c2)B2c4cccc5c4N(c4cc(-c6ccccc6)cc-3c42)c2ccc3ccccc3c2C5(c2ccccc2)c2ccccc2)cc1 ; CC(C)c1cc2c3c(c1)N1c4cc5ccccc5cc4C(c4ccccc4)(c4ccccc4)c4cccc(c41)B3N(c1cccc(C(C)(C)C)c1)c1cc(N(c3ccc(C(C)(C)C)cc3)c3ccc(C(C)(C)C)cc3)ccc1-2] 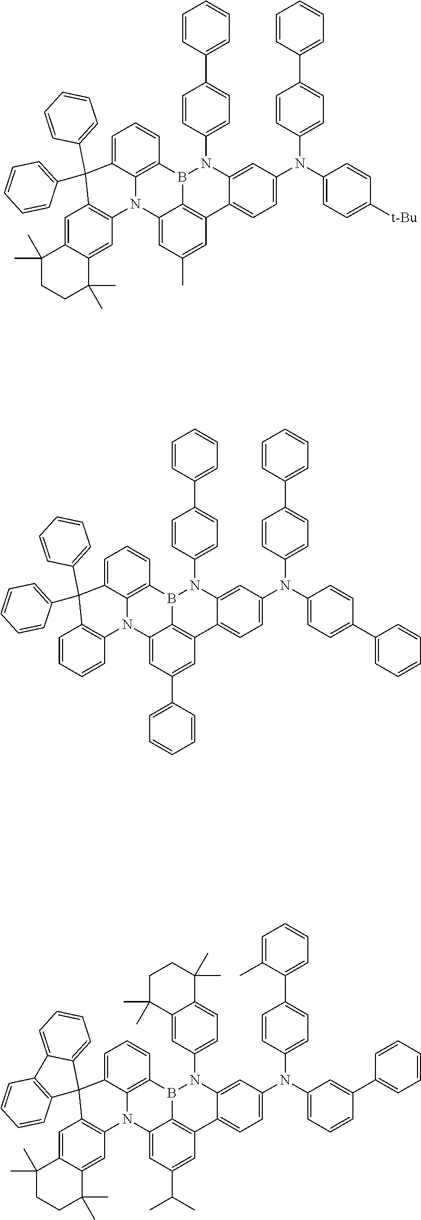 [SMILES: Cc1cc2c3c(c1)N1c4cc5c(cc4C(c4ccccc4)(c4ccccc4)c4cccc(c41)B3N(c1ccc(-c3ccccc3)cc1)c1cc(N(c3ccc(-c4ccccc4)cc3)c3ccc(C(C)(C)C)cc3)ccc1-2)C(C)(C)CCC5(C)C ; c1ccc(-c2ccc(N3B4c5cccc6c5N(c5ccccc5C6(c5ccccc5)c5ccccc5)c5cc(-c6ccccc6)cc(c54)-c4ccc(N(c5ccc(-c6ccccc6)cc5)c5ccc(-c6ccccc6)cc5)cc43)cc2)cc1 ; Cc1ccccc1-c1ccc(N(c2cccc(-c3ccccc3)c2)c2ccc3c(c2)N(c2ccc4c(c2)C(C)(C)CCC4(C)C)B2c4cccc5c4N(c4cc6c(cc4C54c5ccccc5-c5ccccc54)C(C)(C)CCC6(C)C)c4cc(C(C)C)cc-3c42)cc1] 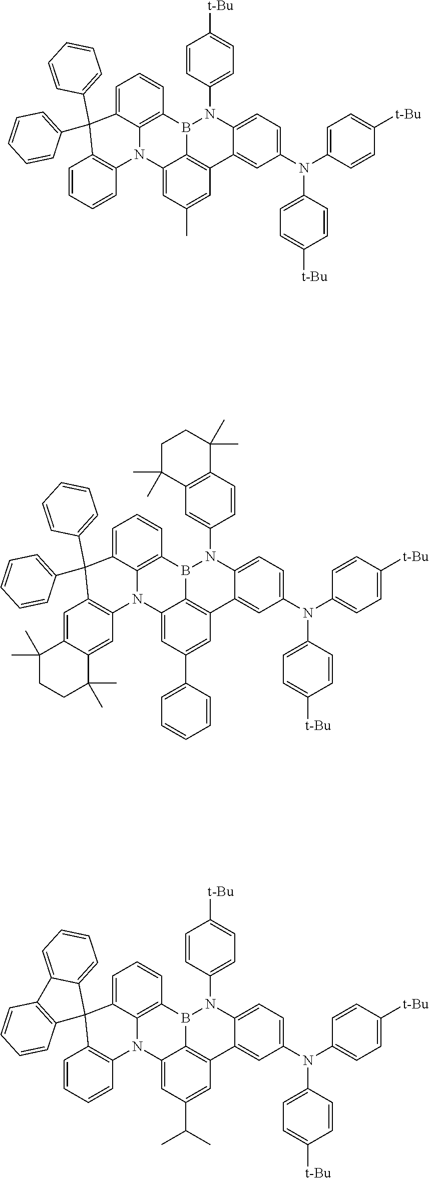 [SMILES: Cc1cc2c3c(c1)N1c4ccccc4C(c4ccccc4)(c4ccccc4)c4cccc(c41)B3N(c1ccc(C(C)(C)C)cc1)c1ccc(N(c3ccc(C(C)(C)C)cc3)c3ccc(C(C)(C)C)cc3)cc1-2 ; CC(C)(C)c1ccc(N(c2ccc(C(C)(C)C)cc2)c2ccc3c(c2)-c2cc(-c4ccccc4)cc4c2B(c2cccc5c2N4c2cc4c(cc2C5(c2ccccc2)c2ccccc2)C(C)(C)CCC4(C)C)N3c2ccc3c(c2)C(C)(C)CCC3(C)C)cc1 ; CC(C)c1cc2c3c(c1)N1c4ccccc4C4(c5ccccc5-c5ccccc54)c4cccc(c41)B3N(c1ccc(C(C)(C)C)cc1)c1ccc(N(c3ccc(C(C)(C)C)cc3)c3ccc(C(C)(C)C)cc3)cc1-2] 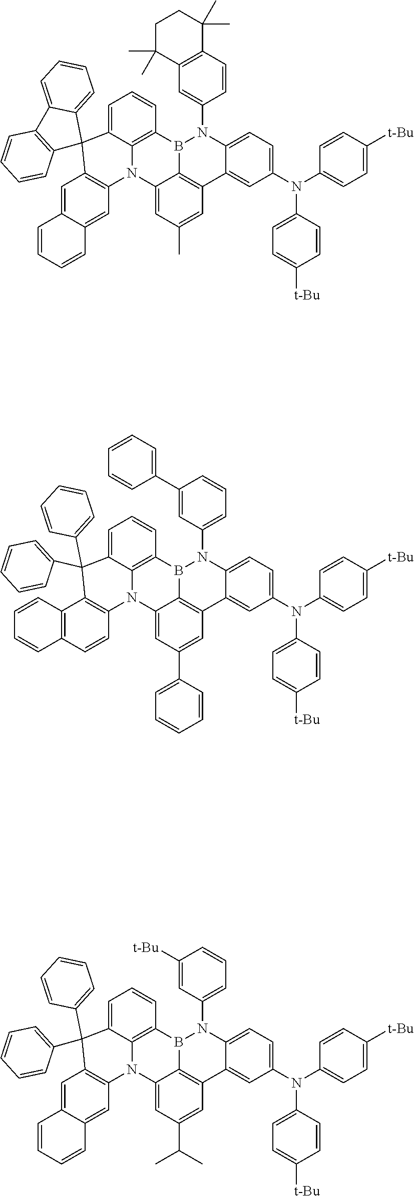 [SMILES: Cc1cc2c3c(c1)N1c4cc5ccccc5cc4C4(c5ccccc5-c5ccccc54)c4cccc(c41)B3N(c1ccc3c(c1)C(C)(C)CCC3(C)C)c1ccc(N(c3ccc(C(C)(C)C)cc3)c3ccc(C(C)(C)C)cc3)cc1-2 ; CC(C)(C)c1ccc(N(c2ccc(C(C)(C)C)cc2)c2ccc3c(c2)-c2cc(-c4ccccc4)cc4c2B(c2cccc5c2N4c2ccc4ccccc4c2C5(c2ccccc2)c2ccccc2)N3c2cccc(-c3ccccc3)c2)cc1 ; CC(C)c1cc2c3c(c1)N1c4cc5ccccc5cc4C(c4ccccc4)(c4ccccc4)c4cccc(c41)B3N(c1cccc(C(C)(C)C)c1)c1ccc(N(c3ccc(C(C)(C)C)cc3)c3ccc(C(C)(C)C)cc3)cc1-2] 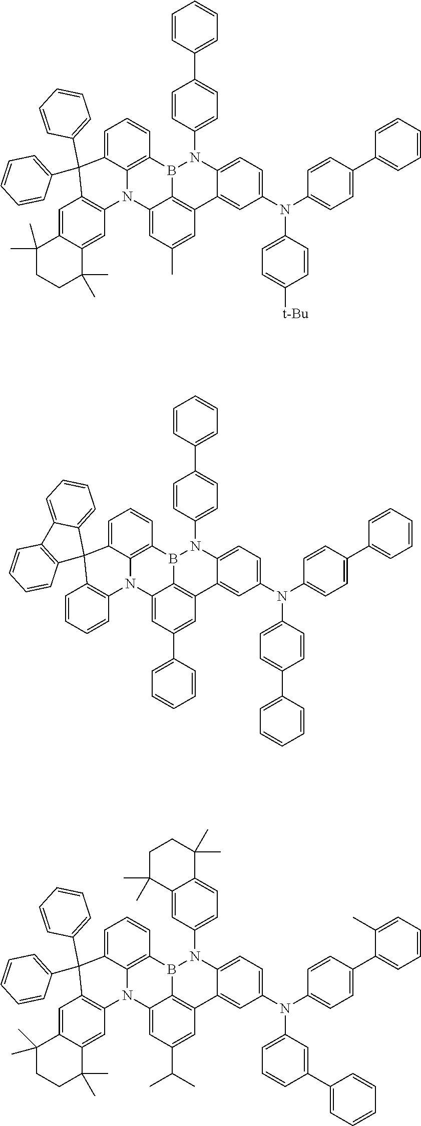 [SMILES: Cc1cc2c3c(c1)N1c4cc5c(cc4C(c4ccccc4)(c4ccccc4)c4cccc(c41)B3N(c1ccc(-c3ccccc3)cc1)c1ccc(N(c3ccc(-c4ccccc4)cc3)c3ccc(C(C)(C)C)cc3)cc1-2)C(C)(C)CCC5(C)C ; c1ccc(-c2ccc(N3B4c5cccc6c5N(c5ccccc5C65c6ccccc6-c6ccccc65)c5cc(-c6ccccc6)cc(c54)-c4cc(N(c5ccc(-c6ccccc6)cc5)c5ccc(-c6ccccc6)cc5)ccc43)cc2)cc1 ; Cc1ccccc1-c1ccc(N(c2cccc(-c3ccccc3)c2)c2ccc3c(c2)-c2cc(C(C)C)cc4c2B(c2cccc5c2N4c2cc4c(cc2C5(c2ccccc2)c2ccccc2)C(C)(C)CCC4(C)C)N3c2ccc3c(c2)C(C)(C)CCC3(C)C)cc1] 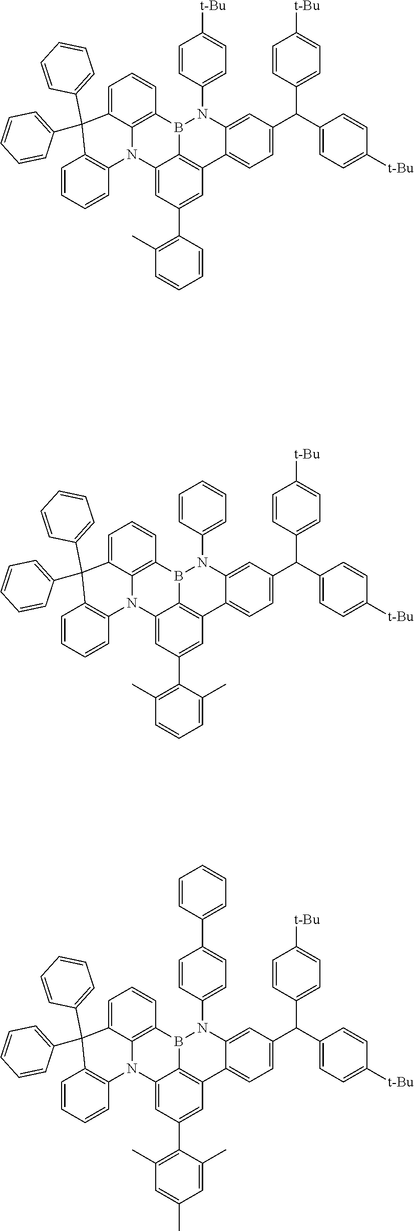 [SMILES: Cc1ccccc1-c1cc2c3c(c1)N1c4ccccc4C(c4ccccc4)(c4ccccc4)c4cccc(c41)B3N(c1ccc(C(C)(C)C)cc1)c1cc(C(c3ccc(C(C)(C)C)cc3)c3ccc(C(C)(C)C)cc3)ccc1-2 ; Cc1cccc(C)c1-c1cc2c3c(c1)N1c4ccccc4C(c4ccccc4)(c4ccccc4)c4cccc(c41)B3N(c1ccccc1)c1cc(C(c3ccc(C(C)(C)C)cc3)c3ccc(C(C)(C)C)cc3)ccc1-2 ; Cc1cc(C)c(-c2cc3c4c(c2)N2c5ccccc5C(c5ccccc5)(c5ccccc5)c5cccc(c52)B4N(c2ccc(-c4ccccc4)cc2)c2cc(C(c4ccc(C(C)(C)C)cc4)c4ccc(C(C)(C)C)cc4)ccc2-3)c(C)c1] 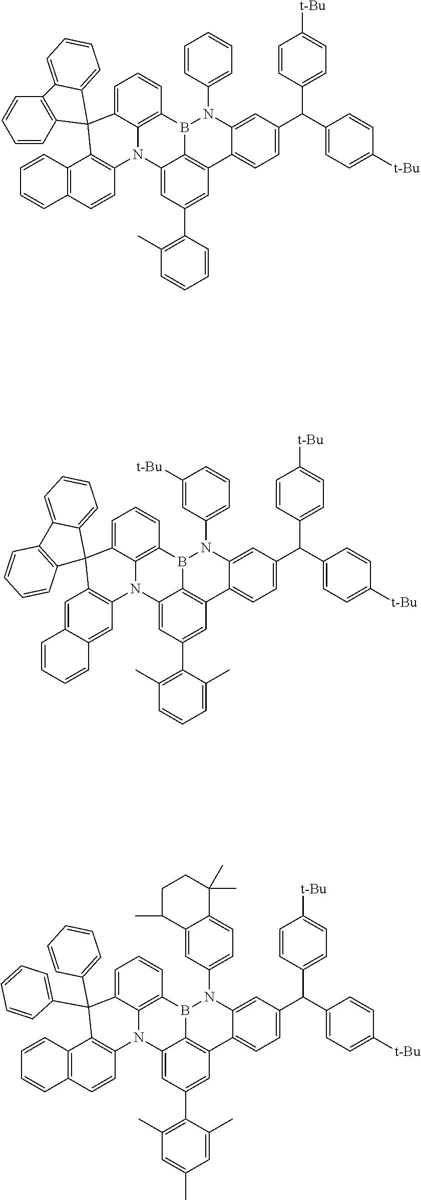 [SMILES: Cc1ccccc1-c1cc2c3c(c1)N1c4ccc5ccccc5c4C4(c5ccccc5-c5ccccc54)c4cccc(c41)B3N(c1ccccc1)c1cc(C(c3ccc(C(C)(C)C)cc3)c3ccc(C(C)(C)C)cc3)ccc1-2 ; Cc1cccc(C)c1-c1cc2c3c(c1)N1c4cc5ccccc5cc4C4(c5ccccc5-c5ccccc54)c4cccc(c41)B3N(c1cccc(C(C)(C)C)c1)c1cc(C(c3ccc(C(C)(C)C)cc3)c3ccc(C(C)(C)C)cc3)ccc1-2 ; Cc1cc(C)c(-c2cc3c4c(c2)N2c5ccc6ccccc6c5C(c5ccccc5)(c5ccccc5)c5cccc(c52)B4N(c2ccc4c(c2)C(C)CCC4(C)C)c2cc(C(c4ccc(C(C)(C)C)cc4)c4ccc(C(C)(C)C)cc4)ccc2-3)c(C)c1] 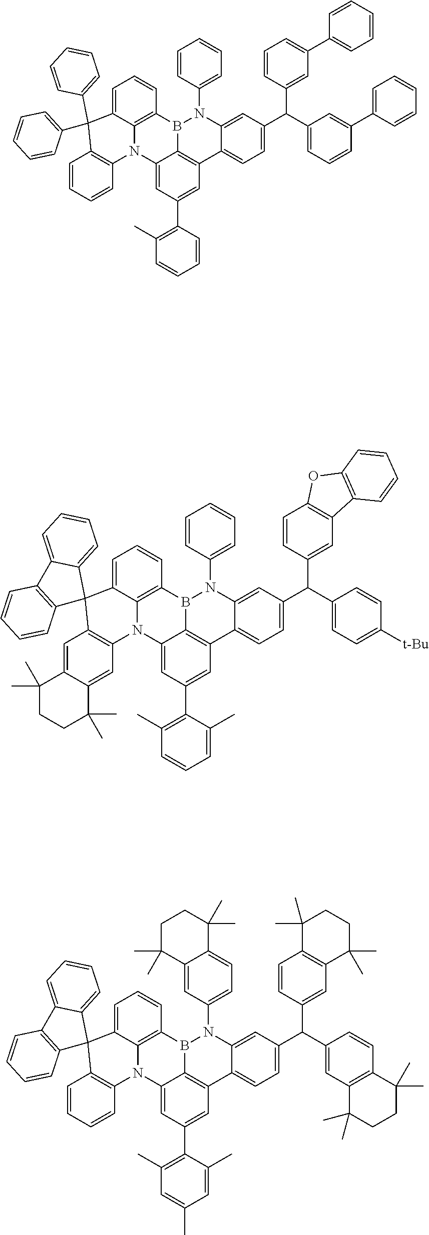 [SMILES: Cc1ccccc1-c1cc2c3c(c1)N1c4ccccc4C(c4ccccc4)(c4ccccc4)c4cccc(c41)B3N(c1ccccc1)c1cc(C(c3cccc(-c4ccccc4)c3)c3cccc(-c4ccccc4)c3)ccc1-2 ; Cc1cccc(C)c1-c1cc2c3c(c1)N1c4cc5c(cc4C4(c6ccccc6-c6ccccc64)c4cccc(c41)B3N(c1ccccc1)c1cc(C(c3ccc(C(C)(C)C)cc3)c3ccc4oc6ccccc6c4c3)ccc1-2)C(C)(C)CCC5(C)C ; Cc1cc(C)c(-c2cc3c4c(c2)N2c5ccccc5C5(c6ccccc6-c6ccccc65)c5cccc(c52)B4N(c2ccc4c(c2)C(C)(C)CCC4(C)C)c2cc(C(c4ccc5c(c4)C(C)(C)CCC5(C)C)c4ccc5c(c4)C(C)(C)CCC5(C)C)ccc2-3)c(C)c1] 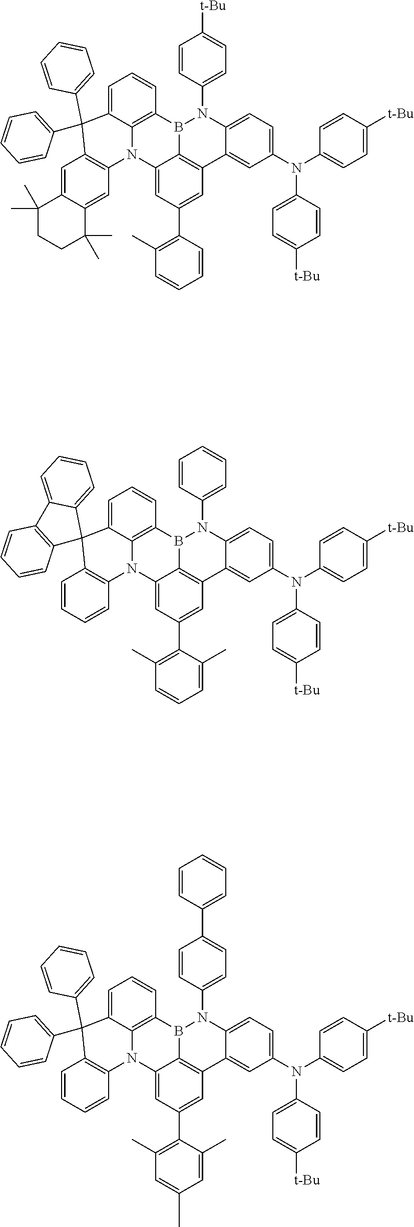 [SMILES: Cc1ccccc1-c1cc2c3c(c1)N1c4cc5c(cc4C(c4ccccc4)(c4ccccc4)c4cccc(c41)B3N(c1ccc(C(C)(C)C)cc1)c1ccc(N(c3ccc(C(C)(C)C)cc3)c3ccc(C(C)(C)C)cc3)cc1-2)C(C)(C)CCC5(C)C ; Cc1cccc(C)c1-c1cc2c3c(c1)N1c4ccccc4C4(c5ccccc5-c5ccccc54)c4cccc(c41)B3N(c1ccccc1)c1ccc(N(c3ccc(C(C)(C)C)cc3)c3ccc(C(C)(C)C)cc3)cc1-2 ; Cc1cc(C)c(-c2cc3c4c(c2)N2c5ccccc5C(c5ccccc5)(c5ccccc5)c5cccc(c52)B4N(c2ccc(-c4ccccc4)cc2)c2ccc(N(c4ccc(C(C)(C)C)cc4)c4ccc(C(C)(C)C)cc4)cc2-3)c(C)c1] 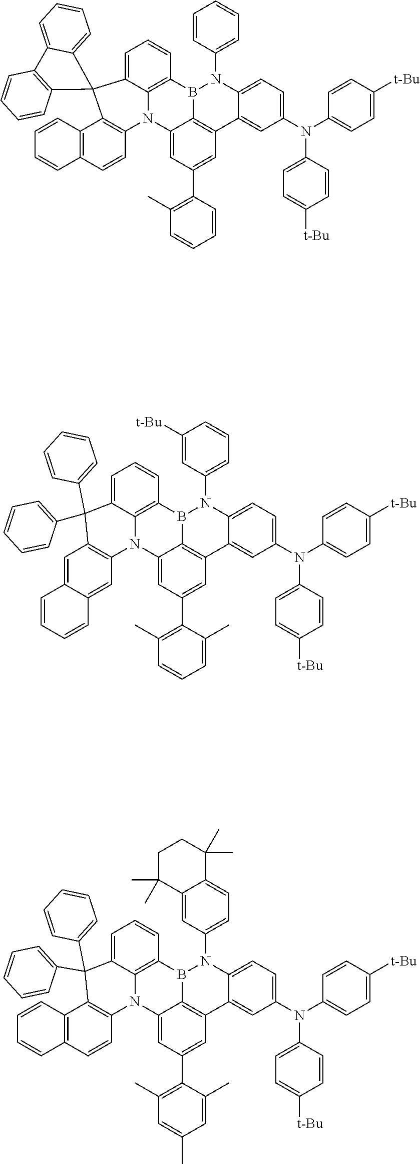 [SMILES: Cc1ccccc1-c1cc2c3c(c1)N1c4ccc5ccccc5c4C4(c5ccccc5-c5ccccc54)c4cccc(c41)B3N(c1ccccc1)c1ccc(N(c3ccc(C(C)(C)C)cc3)c3ccc(C(C)(C)C)cc3)cc1-2 ; Cc1cccc(C)c1-c1cc2c3c(c1)N1c4cc5ccccc5cc4C(c4ccccc4)(c4ccccc4)c4cccc(c41)B3N(c1cccc(C(C)(C)C)c1)c1ccc(N(c3ccc(C(C)(C)C)cc3)c3ccc(C(C)(C)C)cc3)cc1-2 ; Cc1cc(C)c(-c2cc3c4c(c2)N2c5ccc6ccccc6c5C(c5ccccc5)(c5ccccc5)c5cccc(c52)B4N(c2ccc4c(c2)C(C)(C)CCC4(C)C)c2ccc(N(c4ccc(C(C)(C)C)cc4)c4ccc(C(C)(C)C)cc4)cc2-3)c(C)c1] 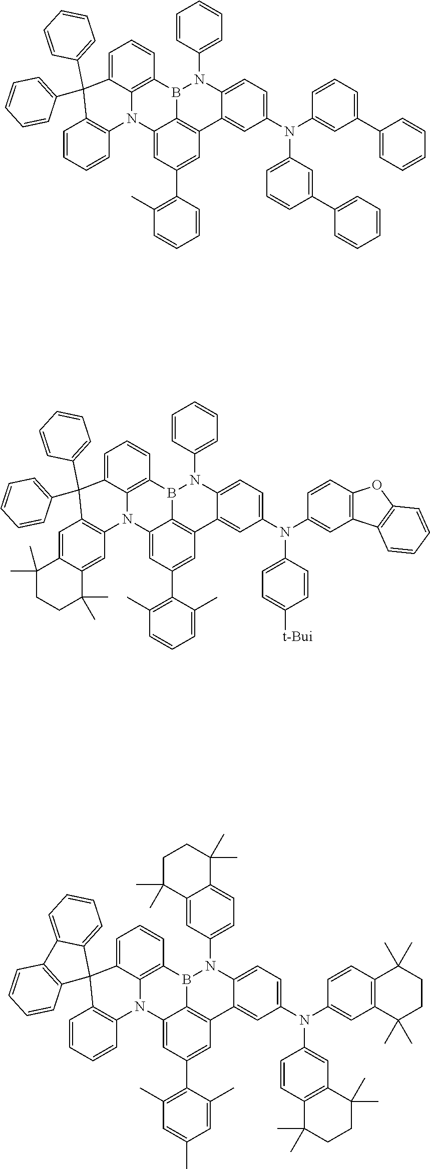 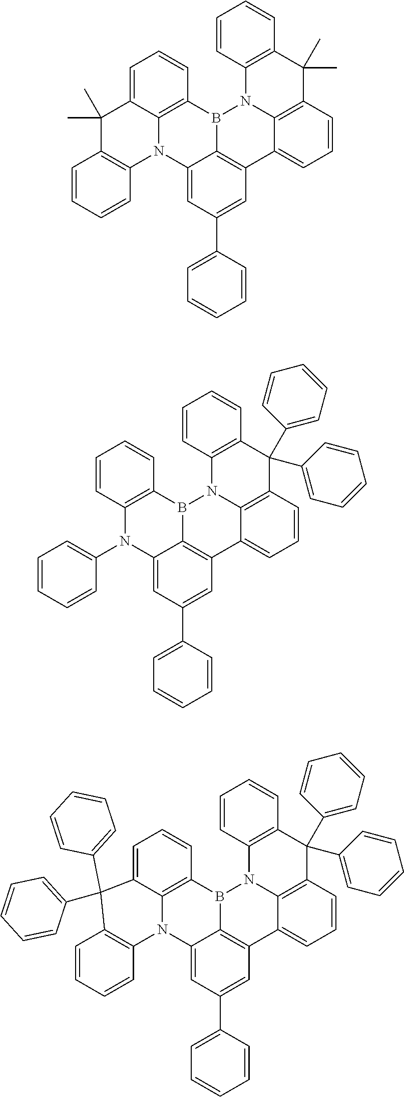 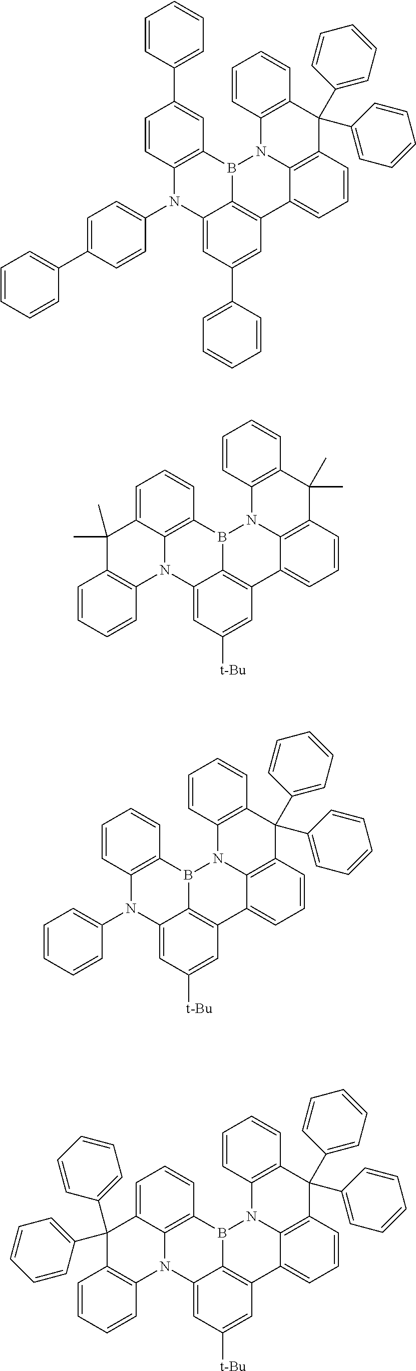 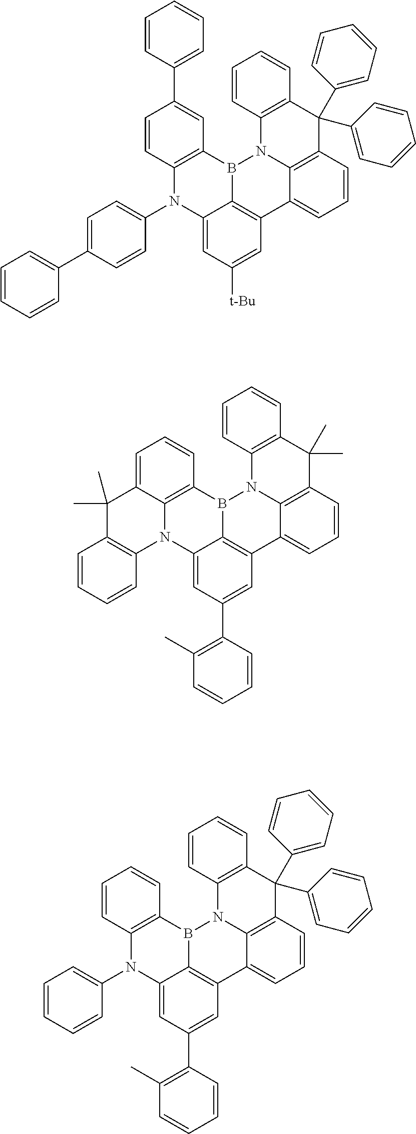 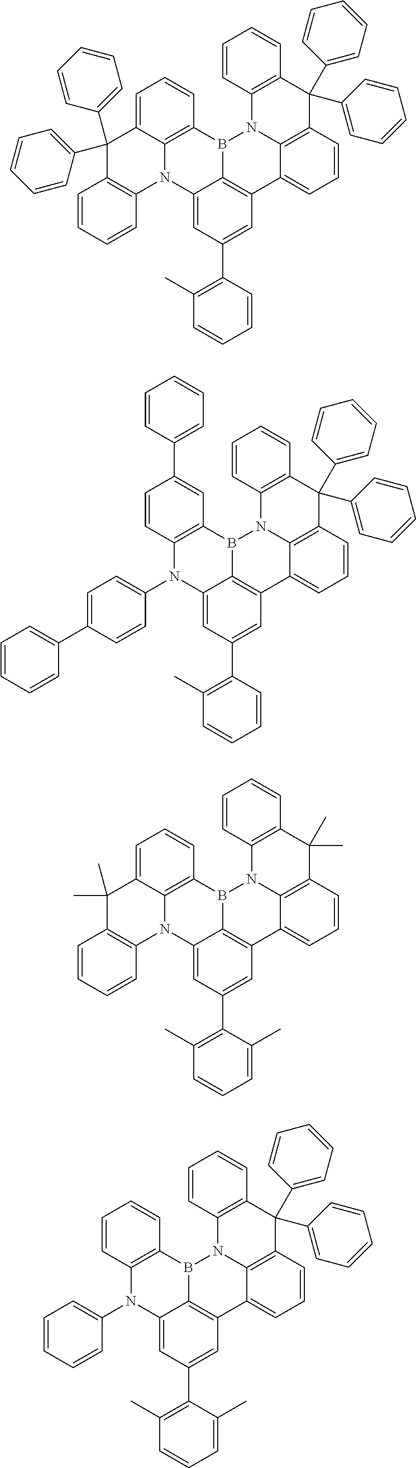 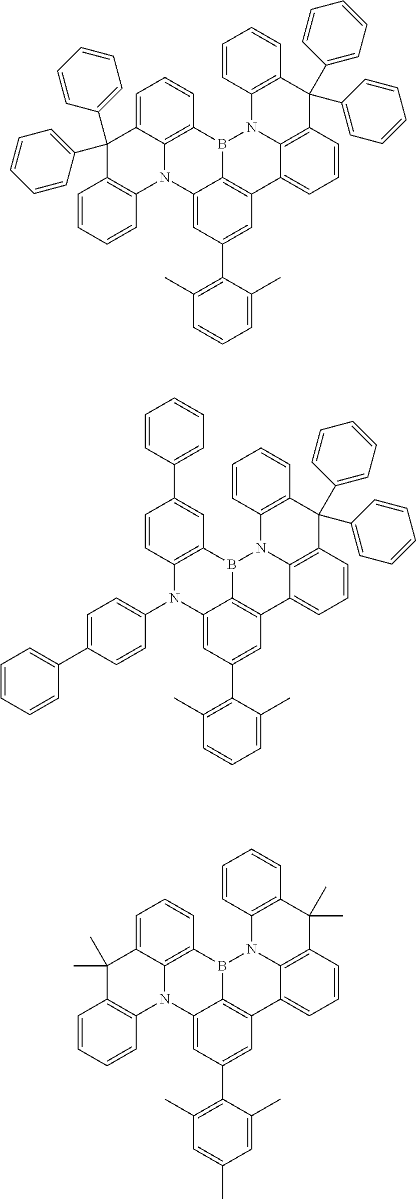 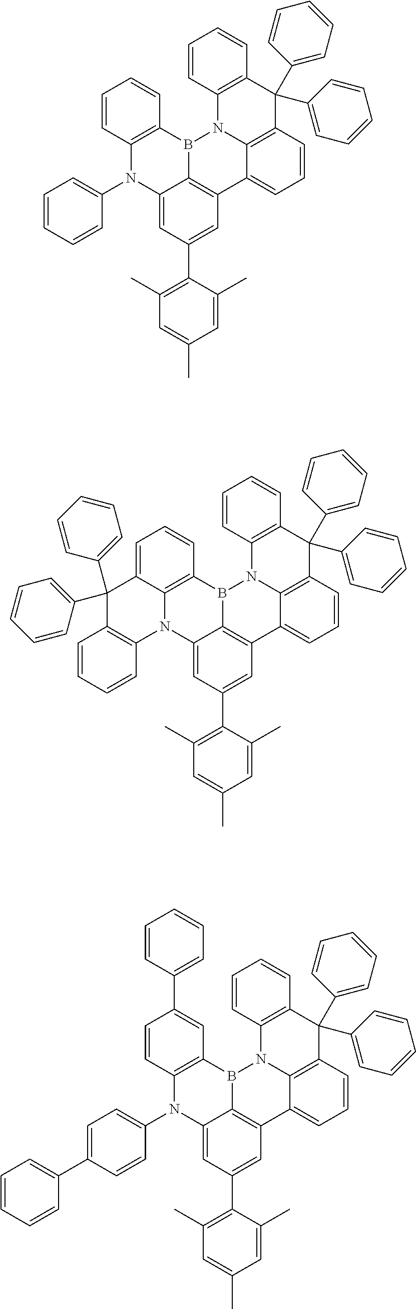 [SMILES: Cc1cc(C)c(-c2cc3c4c(c2)N(c2ccccc2)c2ccccc2B4N2c4ccccc4C(c4ccccc4)(c4ccccc4)c4cccc-3c42)c(C)c1 ; Cc1cc(C)c(-c2cc3c4c(c2)N2c5ccccc5C(c5ccccc5)(c5ccccc5)c5cccc(c52)B4N2c4ccccc4C(c4ccccc4)(c4ccccc4)c4cccc-3c42)c(C)c1 ; Cc1cc(C)c(-c2cc3c4c(c2)N(c2ccc(-c5ccccc5)cc2)c2ccc(-c5ccccc5)cc2B4N2c4ccccc4C(c4ccccc4)(c4ccccc4)c4cccc-3c42)c(C)c1] 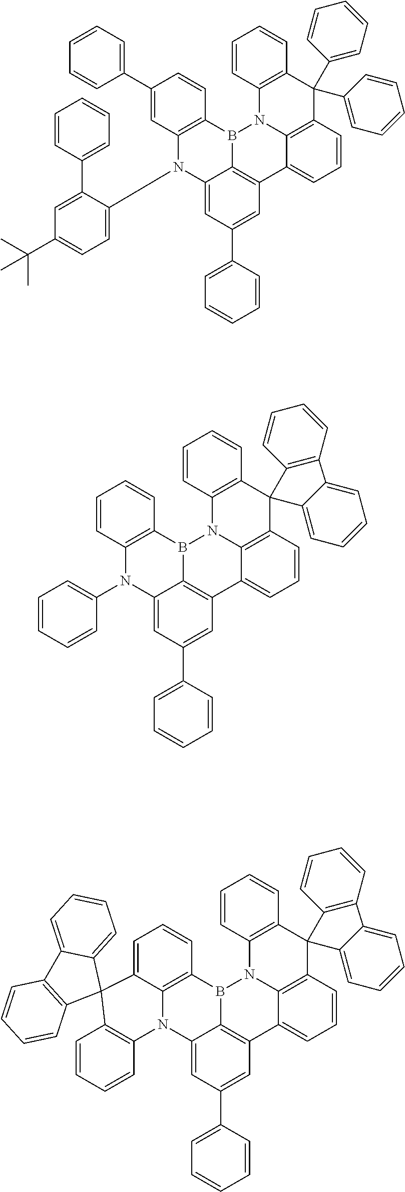 [SMILES: CC(C)(C)c1ccc(N2c3cc(-c4ccccc4)ccc3B3c4c(cc(-c5ccccc5)cc42)-c2cccc4c2N3c2ccccc2C4(c2ccccc2)c2ccccc2)c(-c2ccccc2)c1 ; c1ccc(-c2cc3c4c(c2)N(c2ccccc2)c2ccccc2B4N2c4ccccc4C4(c5ccccc5-c5ccccc54)c4cccc-3c42)cc1 ; c1ccc(-c2cc3c4c(c2)N2c5ccccc5C5(c6ccccc6-c6ccccc65)c5cccc(c52)B4N2c4ccccc4C4(c5ccccc5-c5ccccc54)c4cccc-3c42)cc1] 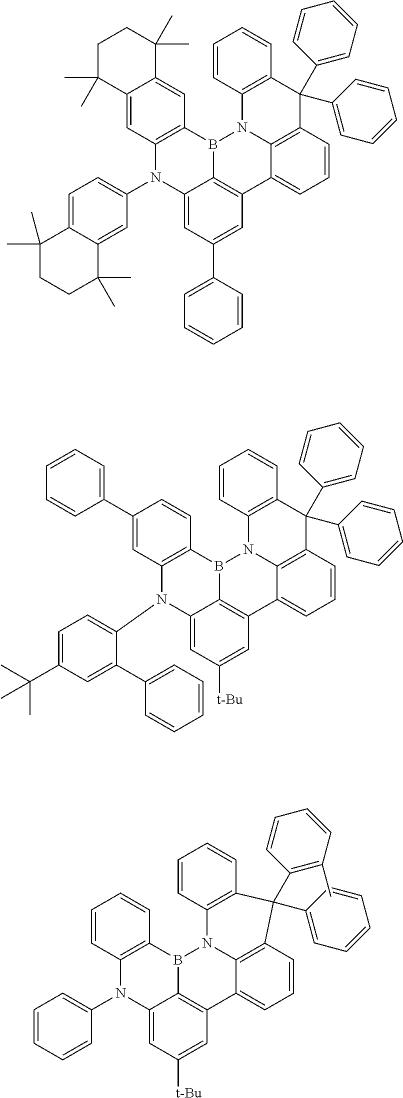 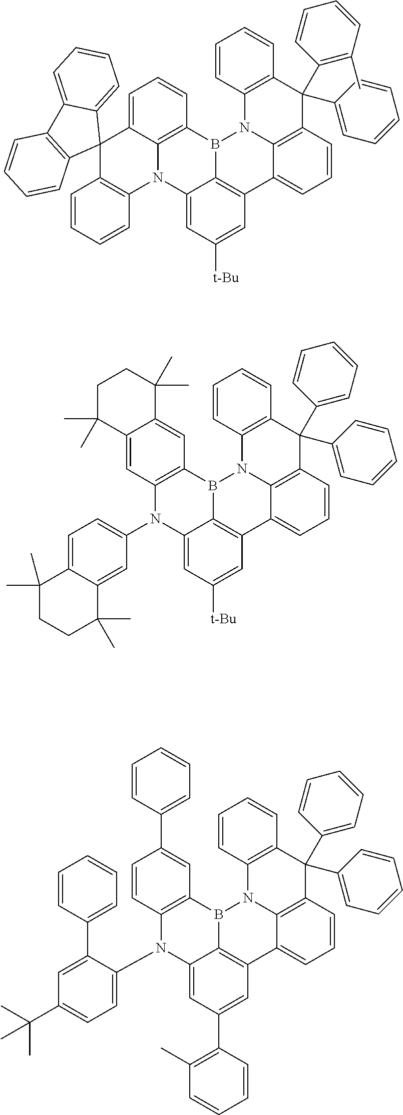 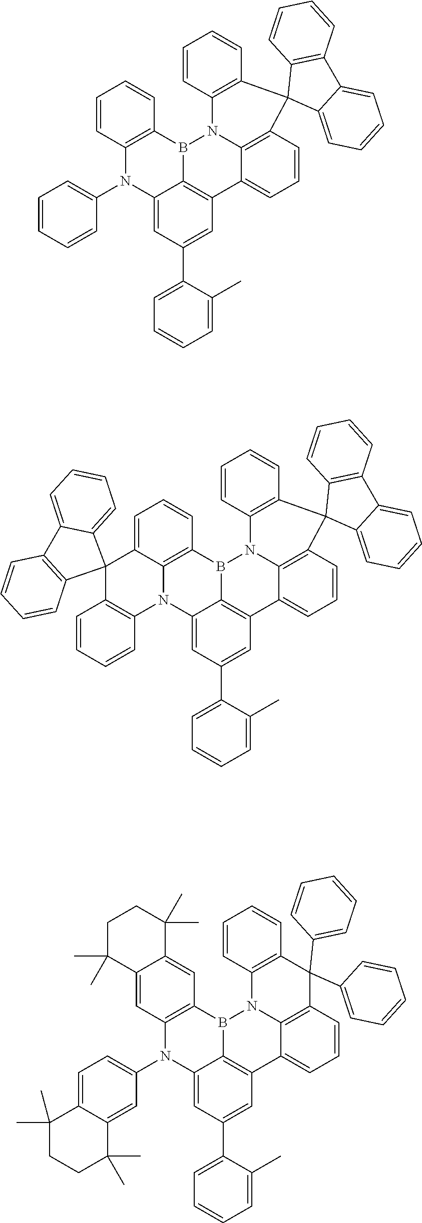 [SMILES: Cc1ccccc1-c1cc2c3c(c1)N(c1ccccc1)c1ccccc1B3N1c3ccccc3C3(c4ccccc4-c4ccccc43)c3cccc-2c31 ; Cc1ccccc1-c1cc2c3c(c1)N1c4ccccc4C4(c5ccccc5-c5ccccc54)c4cccc(c41)B3N1c3ccccc3C3(c4ccccc4-c4ccccc43)c3cccc-2c31 ; Cc1ccccc1-c1cc2c3c(c1)N(c1ccc4c(c1)C(C)(C)CCC4(C)C)c1cc4c(cc1B3N1c3ccccc3C(c3ccccc3)(c3ccccc3)c3cccc-2c31)C(C)(C)CCC4(C)C] 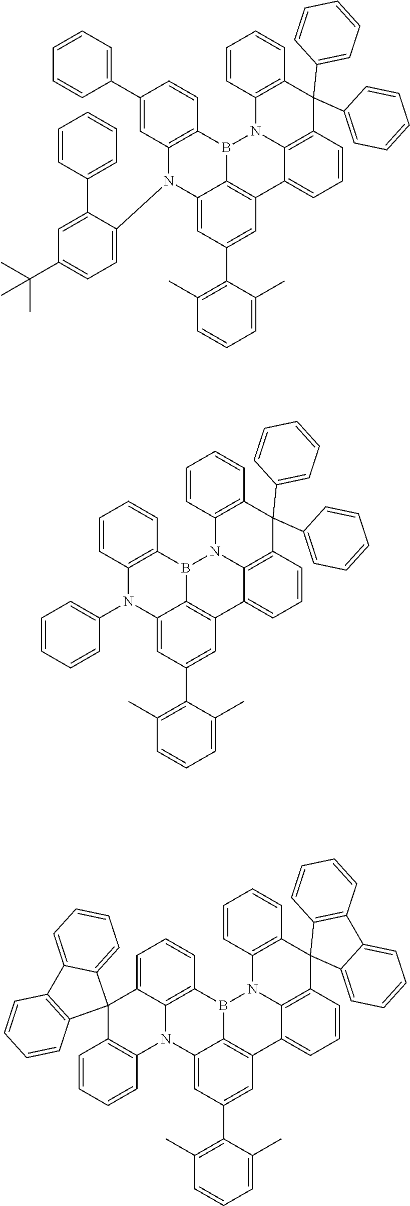 [SMILES: Cc1cccc(C)c1-c1cc2c3c(c1)N(c1ccc(C(C)(C)C)cc1-c1ccccc1)c1cc(-c4ccccc4)ccc1B3N1c3ccccc3C(c3ccccc3)(c3ccccc3)c3cccc-2c31 ; Cc1cccc(C)c1-c1cc2c3c(c1)N(c1ccccc1)c1ccccc1B3N1c3ccccc3C(c3ccccc3)(c3ccccc3)c3cccc-2c31 ; Cc1cccc(C)c1-c1cc2c3c(c1)N1c4ccccc4C4(c5ccccc5-c5ccccc54)c4cccc(c41)B3N1c3ccccc3C3(c4ccccc4-c4ccccc43)c3cccc-2c31] 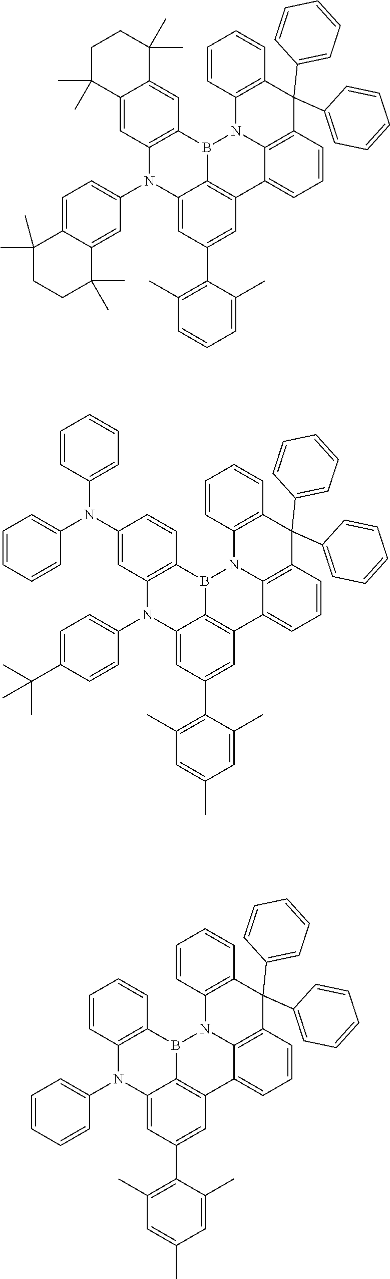 [SMILES: Cc1cccc(C)c1-c1cc2c3c(c1)N(c1ccc4c(c1)C(C)(C)CCC4(C)C)c1cc4c(cc1B3N1c3ccccc3C(c3ccccc3)(c3ccccc3)c3cccc-2c31)C(C)(C)CCC4(C)C ; Cc1cc(C)c(-c2cc3c4c(c2)N(c2ccc(C(C)(C)C)cc2)c2cc(N(c5ccccc5)c5ccccc5)ccc2B4N2c4ccccc4C(c4ccccc4)(c4ccccc4)c4cccc-3c42)c(C)c1 ; Cc1cc(C)c(-c2cc3c4c(c2)N(c2ccccc2)c2ccccc2B4N2c4ccccc4C(c4ccccc4)(c4ccccc4)c4cccc-3c42)c(C)c1] 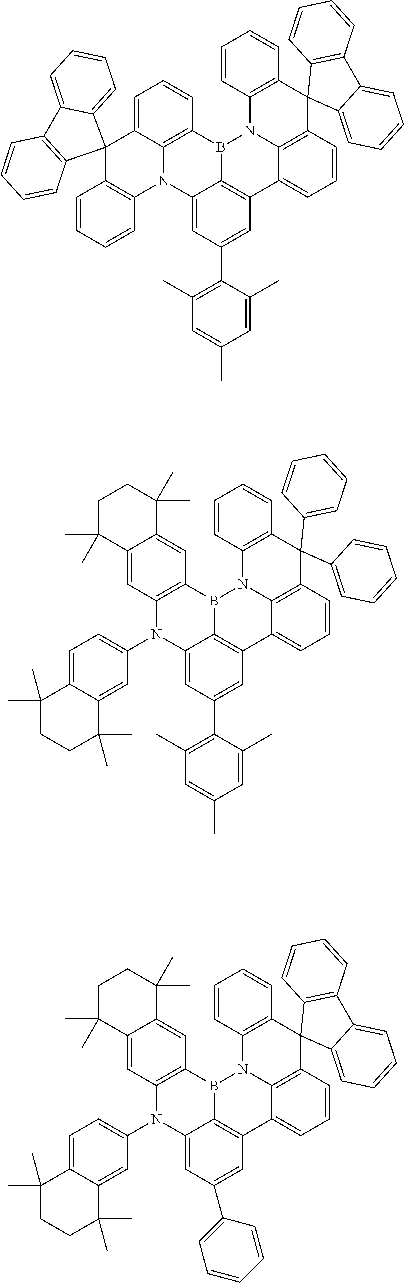 [SMILES: Cc1cc(C)c(-c2cc3c4c(c2)N2c5ccccc5C5(c6ccccc6-c6ccccc65)c5cccc(c52)B4N2c4ccccc4C4(c5ccccc5-c5ccccc54)c4cccc-3c42)c(C)c1 ; Cc1cc(C)c(-c2cc3c4c(c2)N(c2ccc5c(c2)C(C)(C)CCC5(C)C)c2cc5c(cc2B4N2c4ccccc4C(c4ccccc4)(c4ccccc4)c4cccc-3c42)C(C)(C)CCC5(C)C)c(C)c1 ; CC1(C)CCC(C)(C)c2cc(N3c4cc5c(cc4B4c6c(cc(-c7ccccc7)cc63)-c3cccc6c3N4c3ccccc3C63c4ccccc4-c4ccccc43)C(C)(C)CCC5(C)C)ccc21] 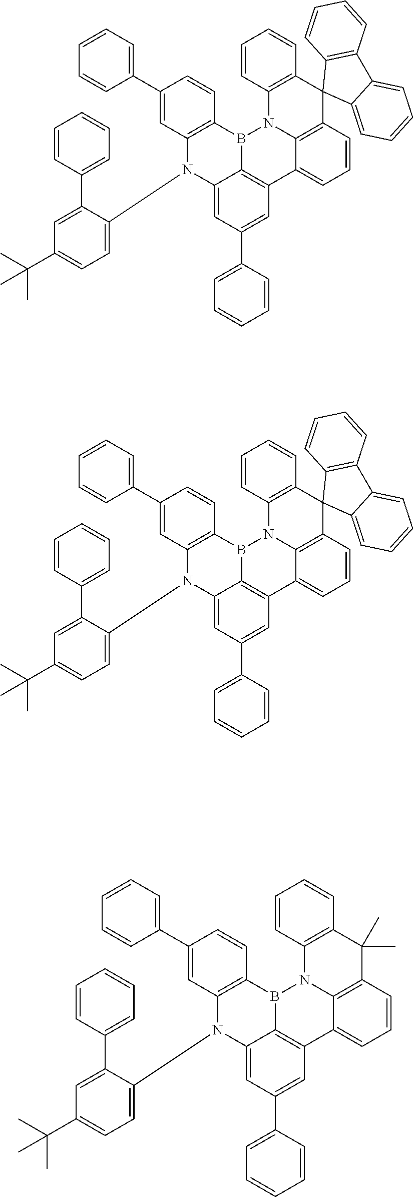 [SMILES: CC(C)(C)c1ccc(N2c3cc(-c4ccccc4)ccc3B3c4c(cc(-c5ccccc5)cc42)-c2cccc4c2N3c2ccccc2C42c3ccccc3-c3ccccc32)c(-c2ccccc2)c1 ; CC(C)(C)c1ccc(N2c3cc(-c4ccccc4)ccc3B3c4c(cc(-c5ccccc5)cc42)-c2cccc4c2N3c2ccccc2C42c3ccccc3-c3ccccc32)c(-c2ccccc2)c1 ; CC(C)(C)c1ccc(N2c3cc(-c4ccccc4)ccc3B3c4c(cc(-c5ccccc5)cc42)-c2cccc4c2N3c2ccccc2C4(C)C)c(-c2ccccc2)c1] 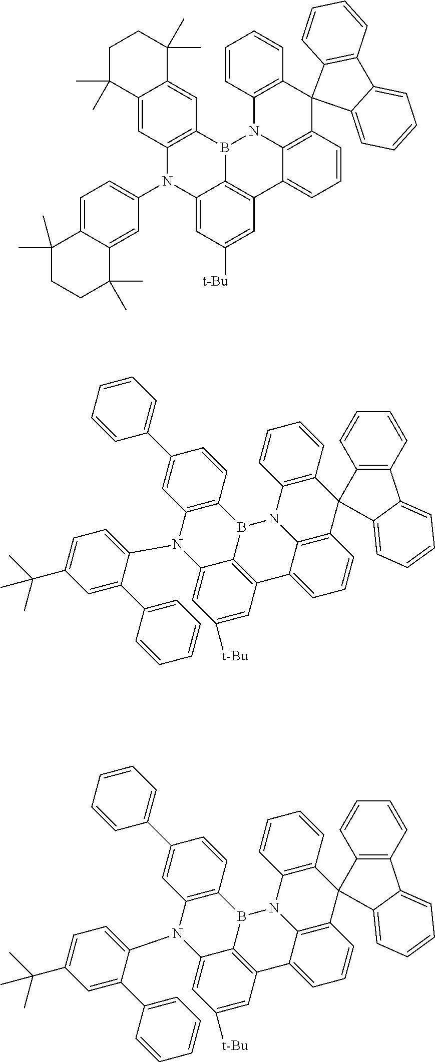 [SMILES: CC(C)(C)c1cc2c3c(c1)N(c1ccc4c(c1)C(C)(C)CCC4(C)C)c1cc4c(cc1B3N1c3ccccc3C3(c5ccccc5-c5ccccc53)c3cccc-2c31)C(C)(C)CCC4(C)C ; CC(C)(C)c1ccc(N2c3cc(-c4ccccc4)ccc3B3c4c(cc(C(C)(C)C)cc42)-c2cccc4c2N3c2ccccc2C42c3ccccc3-c3ccccc32)c(-c2ccccc2)c1 ; CC(C)(C)c1ccc(N2c3cc(-c4ccccc4)ccc3B3c4c(cc(C(C)(C)C)cc42)-c2cccc4c2N3c2ccccc2C42c3ccccc3-c3ccccc32)c(-c2ccccc2)c1] 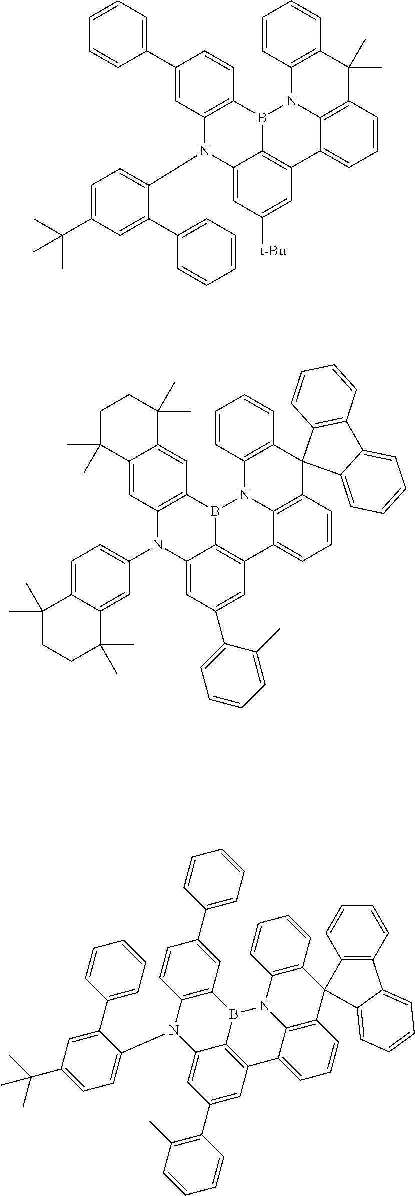 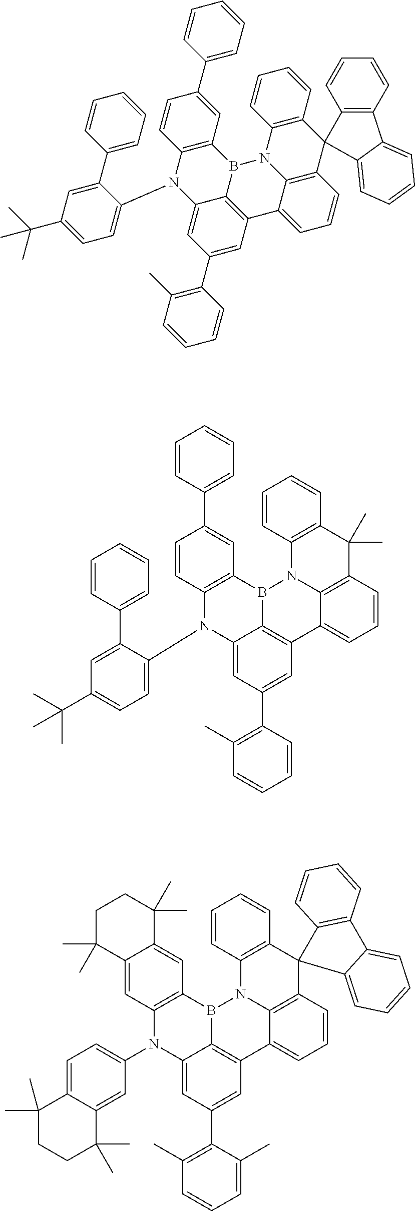 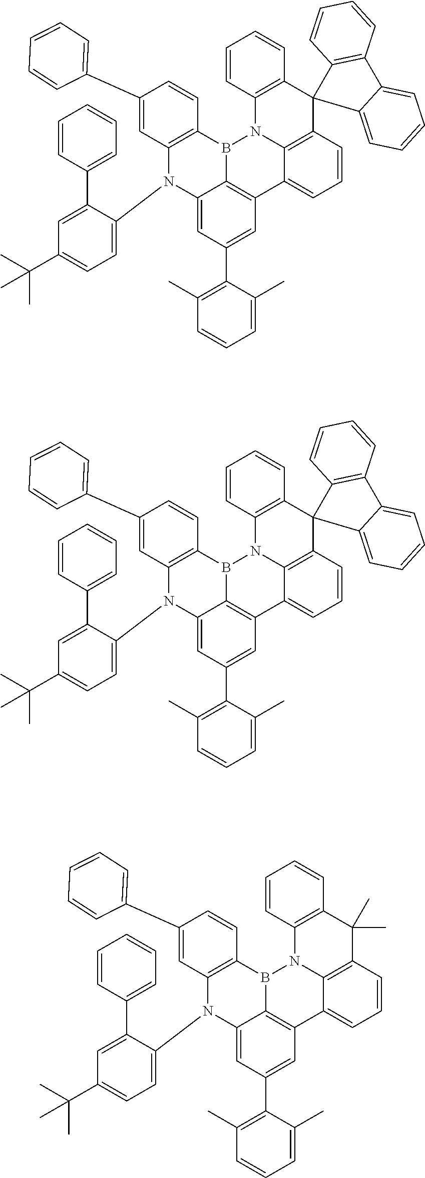 [SMILES: Cc1cccc(C)c1-c1cc2c3c(c1)N(c1ccc(C(C)(C)C)cc1-c1ccccc1)c1cc(-c4ccccc4)ccc1B3N1c3ccccc3C3(c4ccccc4-c4ccccc43)c3cccc-2c31 ; Cc1cccc(C)c1-c1cc2c3c(c1)N(c1ccc(C(C)(C)C)cc1-c1ccccc1)c1cc(-c4ccccc4)ccc1B3N1c3ccccc3C3(c4ccccc4-c4ccccc43)c3cccc-2c31 ; Cc1cccc(C)c1-c1cc2c3c(c1)N(c1ccc(C(C)(C)C)cc1-c1ccccc1)c1cc(-c4ccccc4)ccc1B3N1c3ccccc3C(C)(C)c3cccc-2c31] 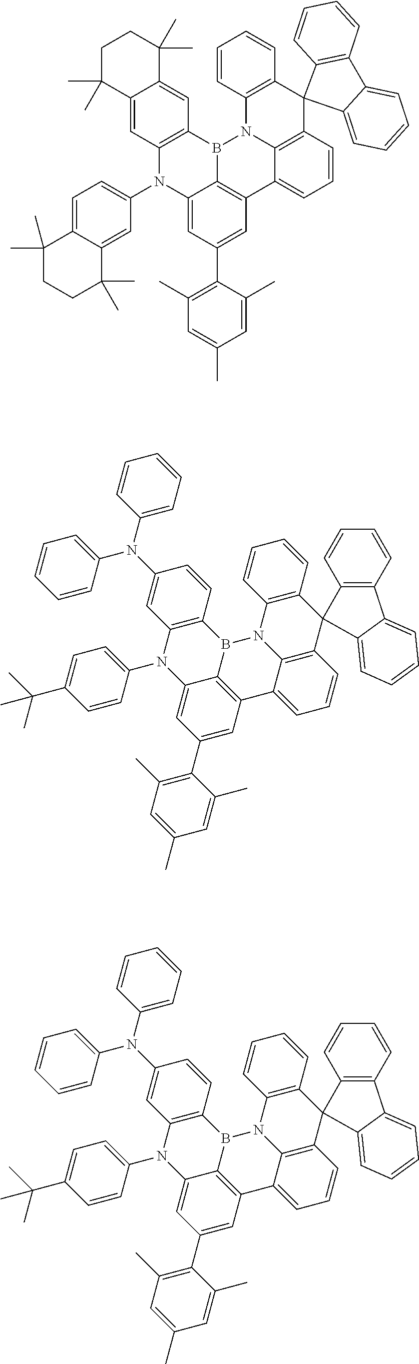 [SMILES: Cc1cc(C)c(-c2cc3c4c(c2)N(c2ccc5c(c2)C(C)(C)CCC5(C)C)c2cc5c(cc2B4N2c4ccccc4C4(c6ccccc6-c6ccccc64)c4cccc-3c42)C(C)(C)CCC5(C)C)c(C)c1 ; Cc1cc(C)c(-c2cc3c4c(c2)N(c2ccc(C(C)(C)C)cc2)c2cc(N(c5ccccc5)c5ccccc5)ccc2B4N2c4ccccc4C4(c5ccccc5-c5ccccc54)c4cccc-3c42)c(C)c1 ; Cc1cc(C)c(-c2cc3c4c(c2)N(c2ccc(C(C)(C)C)cc2)c2cc(N(c5ccccc5)c5ccccc5)ccc2B4N2c4ccccc4C4(c5ccccc5-c5ccccc54)c4cccc-3c42)c(C)c1] 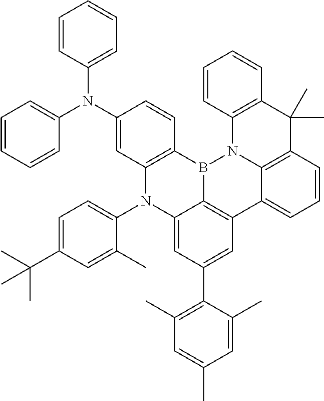 [SMILES: Cc1cc(C)c(-c2cc3c4c(c2)N(c2ccc(C(C)(C)C)cc2C)c2cc(N(c5ccccc5)c5ccccc5)ccc2B4N2c4ccccc4C(C)(C)c4cccc-3c42)c(C)c1] 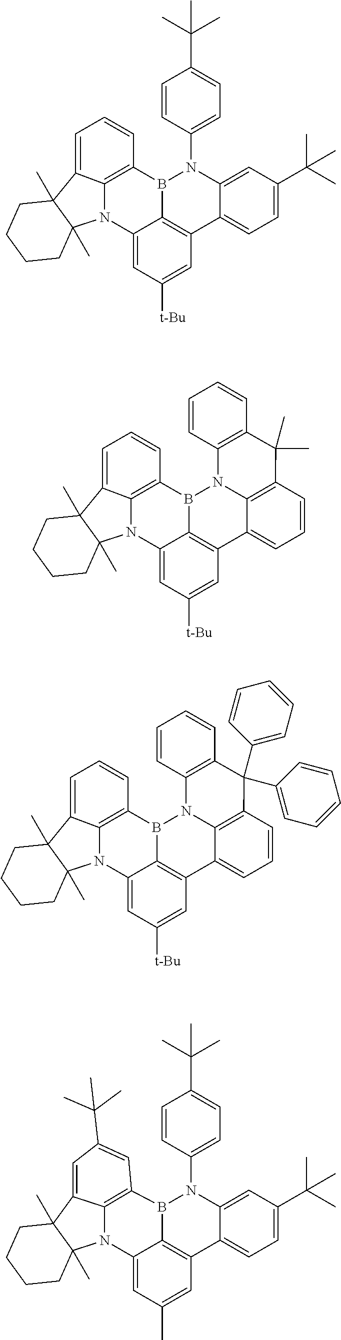 [SMILES: CC(C)(C)c1ccc(N2B3c4cccc5c4N(c4cc(C(C)(C)C)cc(c43)-c3ccc(C(C)(C)C)cc32)C2(C)CCCCC52C)cc1 ; CC(C)(C)c1cc2c3c(c1)N1c4c(cccc4C4(C)CCCCC14C)B3N1c3ccccc3C(C)(C)c3cccc-2c31 ; CC(C)(C)c1cc2c3c(c1)N1c4c(cccc4C4(C)CCCCC14C)B3N1c3ccccc3C(c3ccccc3)(c3ccccc3)c3cccc-2c31 ; Cc1cc2c3c(c1)N1c4c(cc(C(C)(C)C)cc4C4(C)CCCCC14C)B3N(c1ccc(C(C)(C)C)cc1)c1cc(C(C)(C)C)ccc1-2] 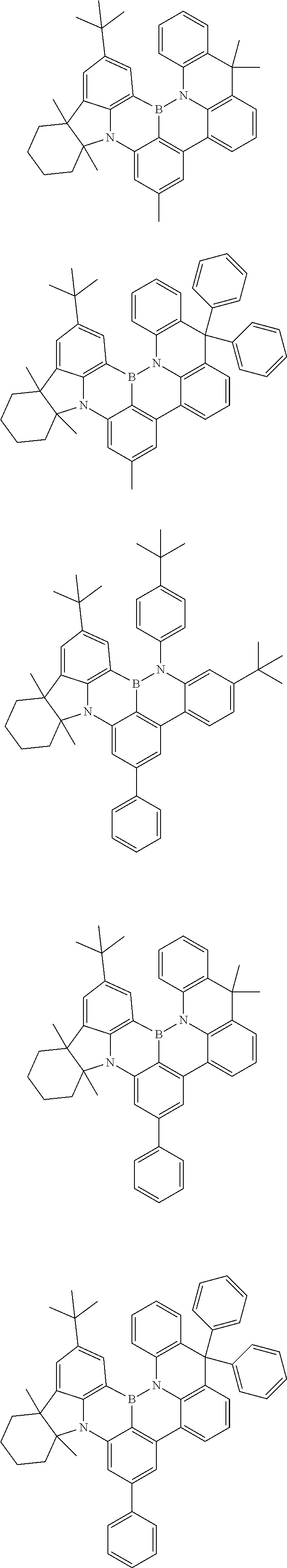 [SMILES: Cc1cc2c3c(c1)N1c4c(cc(C(C)(C)C)cc4C4(C)CCCCC14C)B3N1c3ccccc3C(C)(C)c3cccc-2c31 ; Cc1cc2c3c(c1)N1c4c(cc(C(C)(C)C)cc4C4(C)CCCCC14C)B3N1c3ccccc3C(c3ccccc3)(c3ccccc3)c3cccc-2c31 ; CC(C)(C)c1ccc(N2B3c4cc(C(C)(C)C)cc5c4N(c4cc(-c6ccccc6)cc(c43)-c3ccc(C(C)(C)C)cc32)C2(C)CCCCC52C)cc1 ; CC(C)(C)c1cc2c3c(c1)C1(C)CCCCC1(C)N3c1cc(-c3ccccc3)cc3c1B2N1c2ccccc2C(C)(C)c2cccc-3c21 ; CC(C)(C)c1cc2c3c(c1)C1(C)CCCCC1(C)N3c1cc(-c3ccccc3)cc3c1B2N1c2ccccc2C(c2ccccc2)(c2ccccc2)c2cccc-3c21] 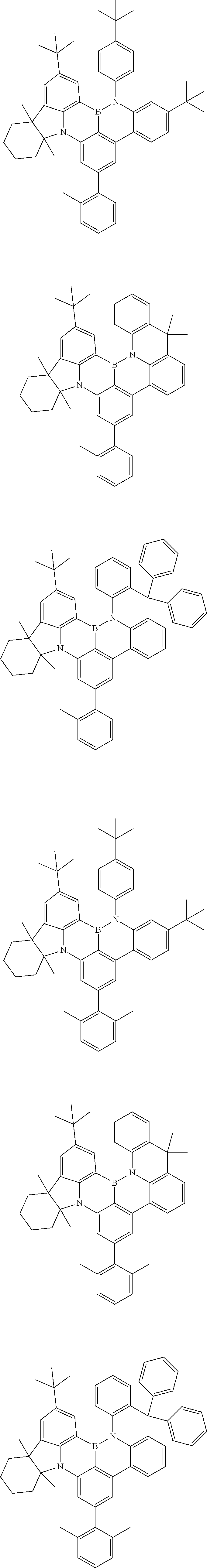 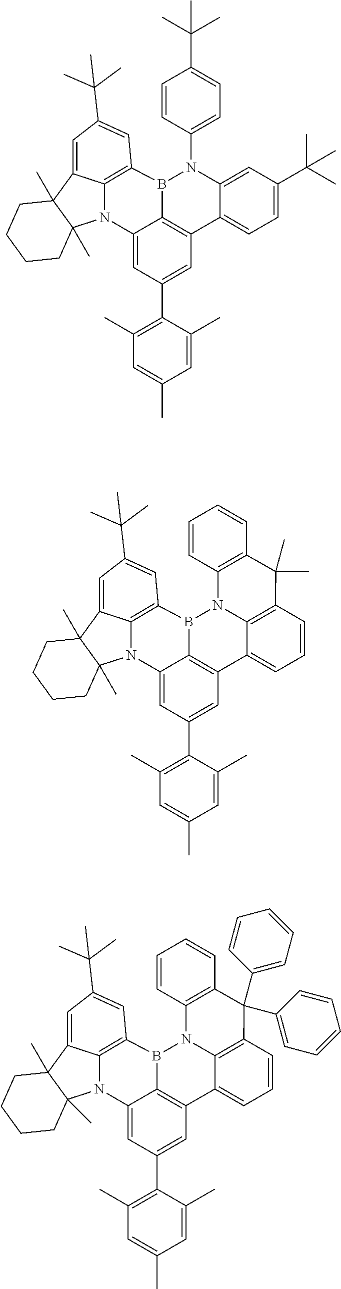 [SMILES: Cc1cc(C)c(-c2cc3c4c(c2)N2c5c(cc(C(C)(C)C)cc5C5(C)CCCCC25C)B4N(c2ccc(C(C)(C)C)cc2)c2cc(C(C)(C)C)ccc2-3)c(C)c1 ; Cc1cc(C)c(-c2cc3c4c(c2)N2c5c(cc(C(C)(C)C)cc5C5(C)CCCCC25C)B4N2c4ccccc4C(C)(C)c4cccc-3c42)c(C)c1 ; Cc1cc(C)c(-c2cc3c4c(c2)N2c5c(cc(C(C)(C)C)cc5C5(C)CCCCC25C)B4N2c4ccccc4C(c4ccccc4)(c4ccccc4)c4cccc-3c42)c(C)c1] 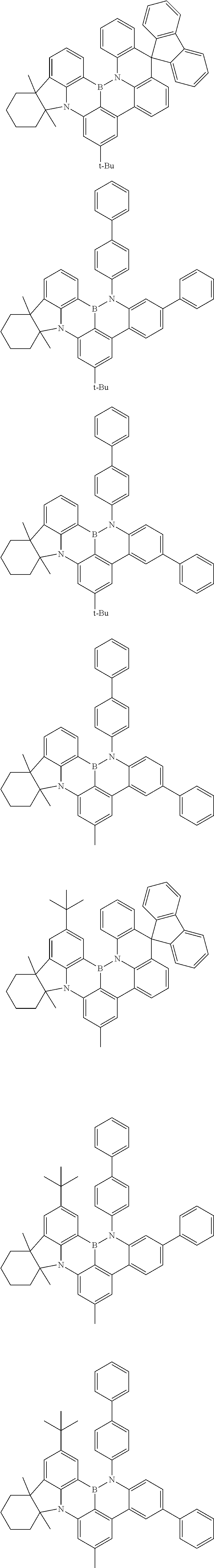 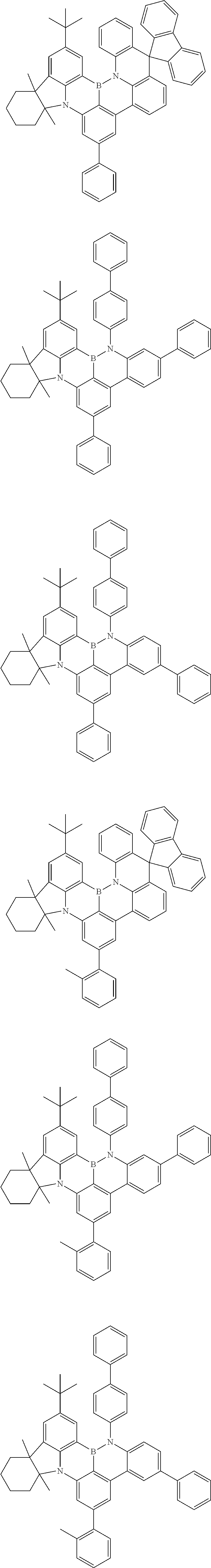 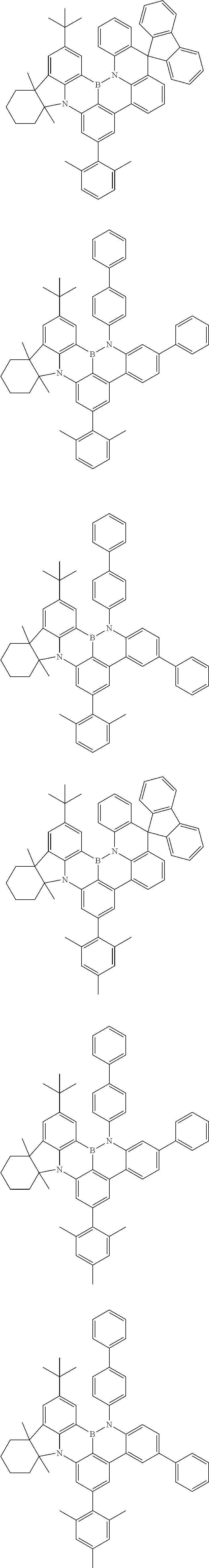 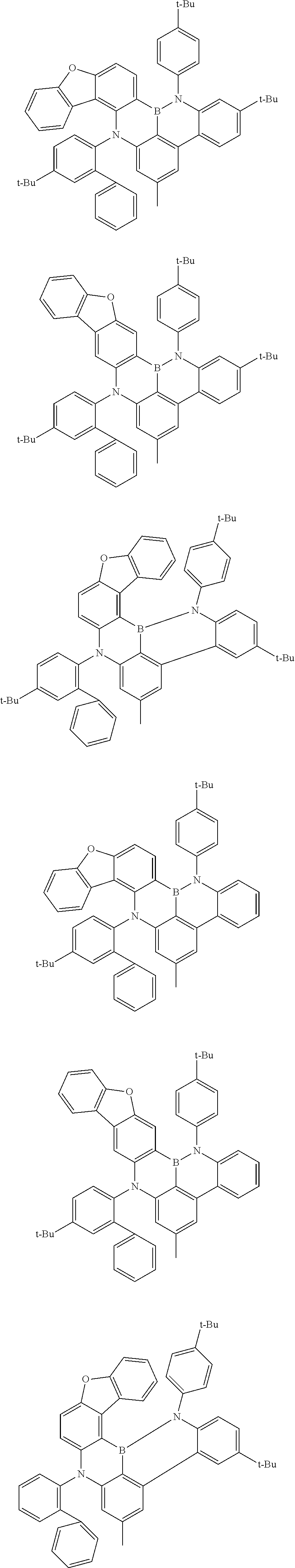 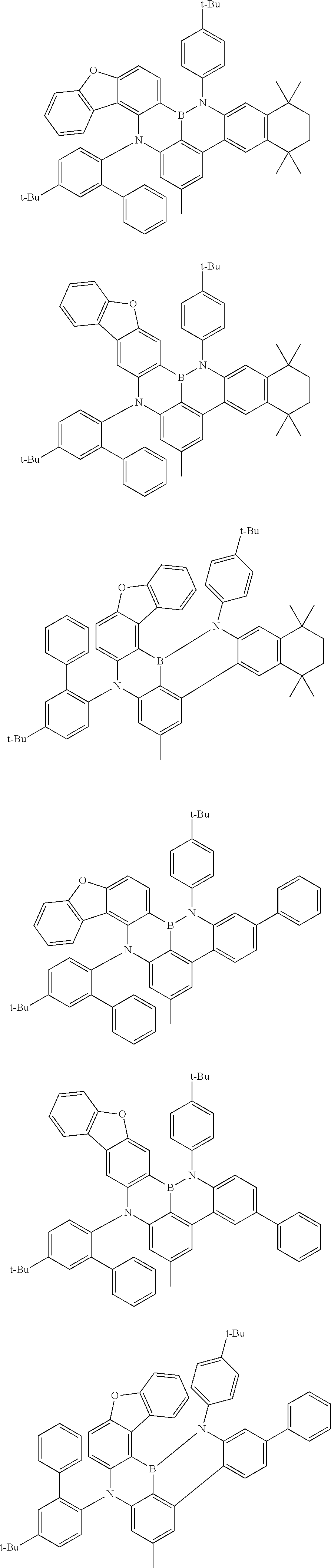 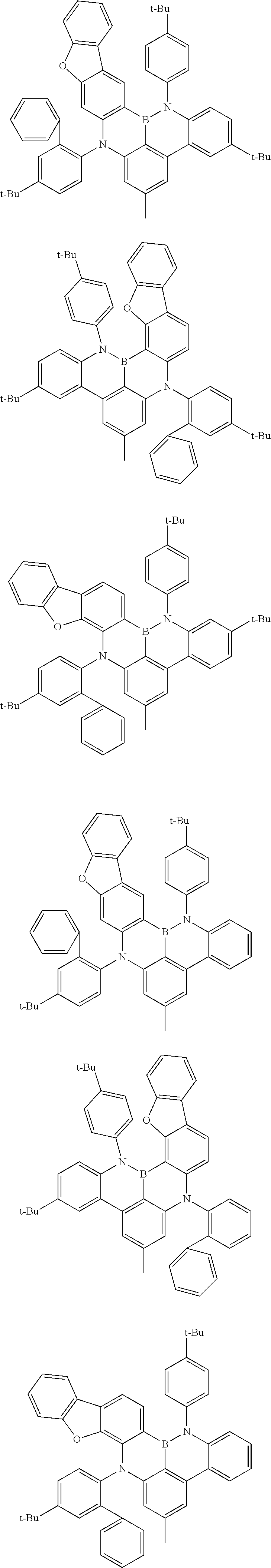 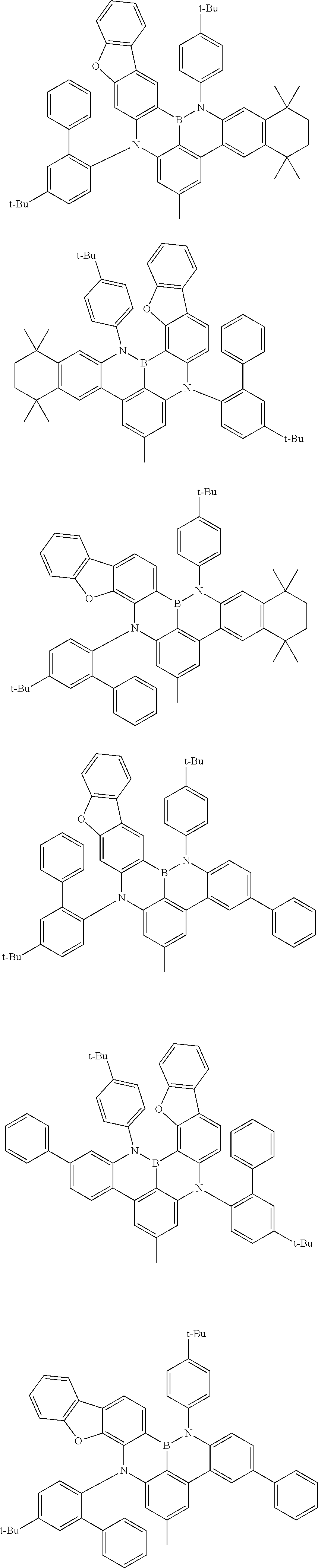 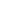 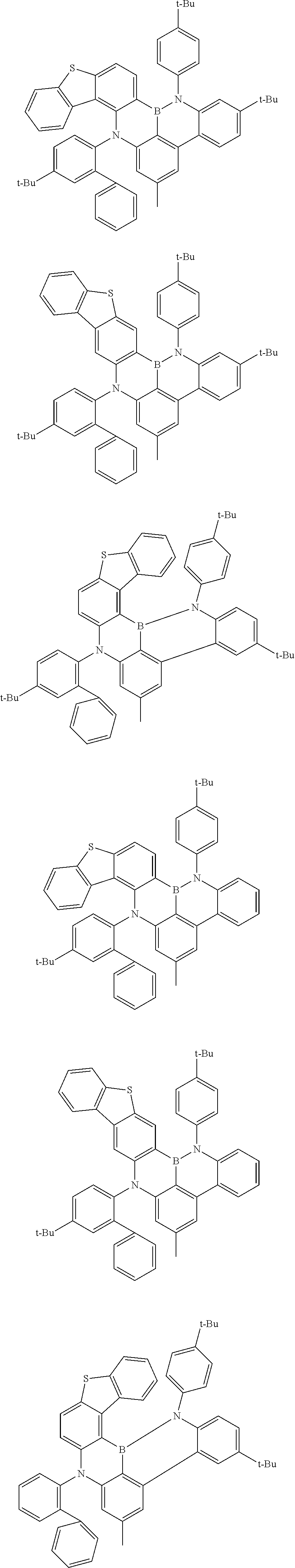 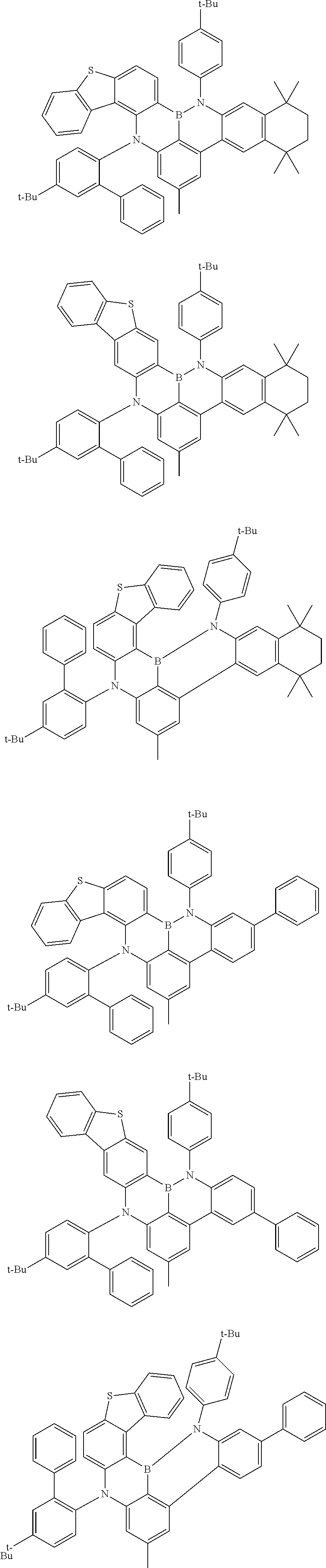 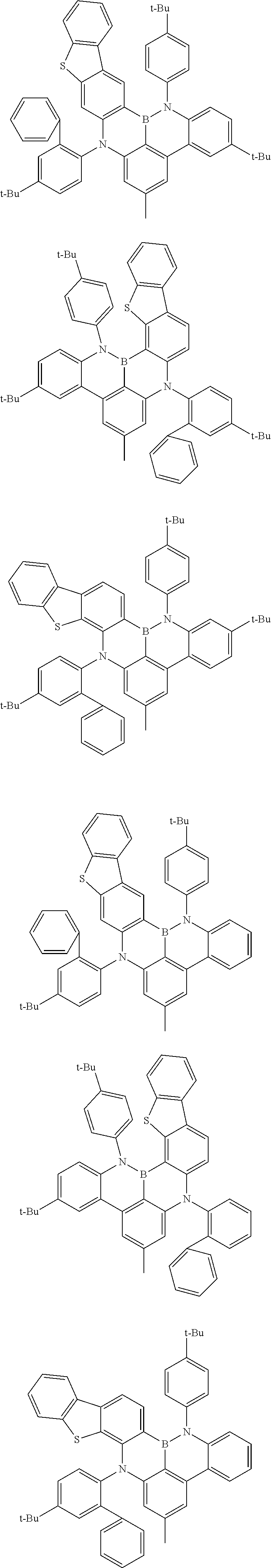 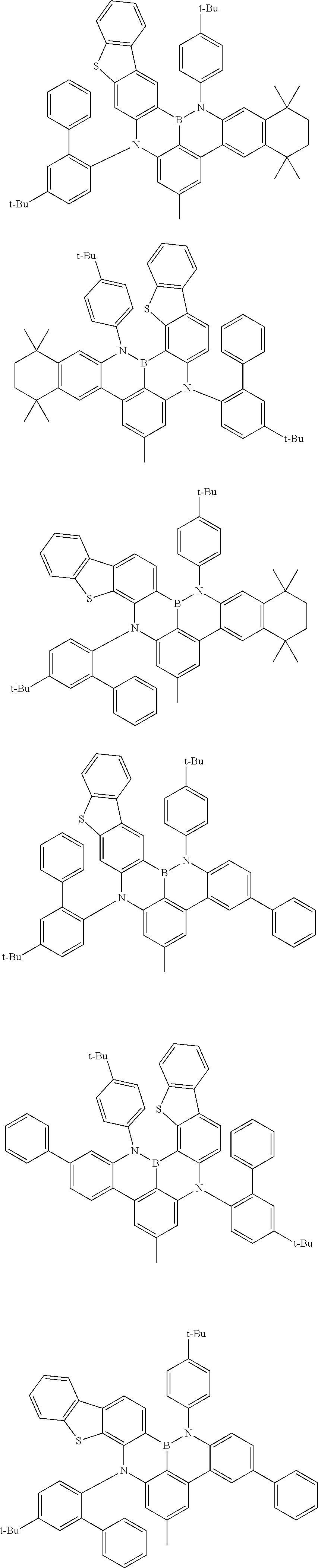 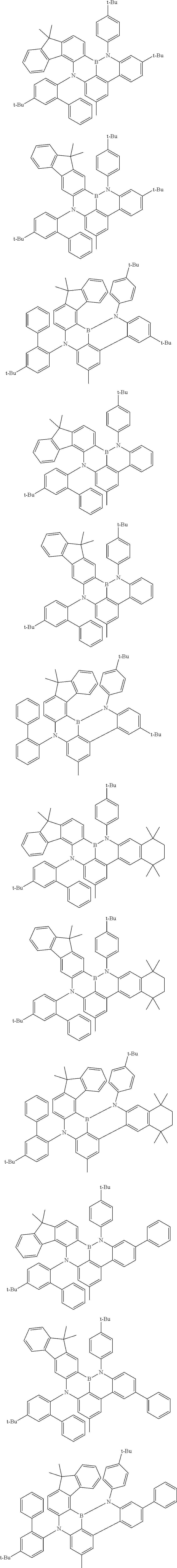 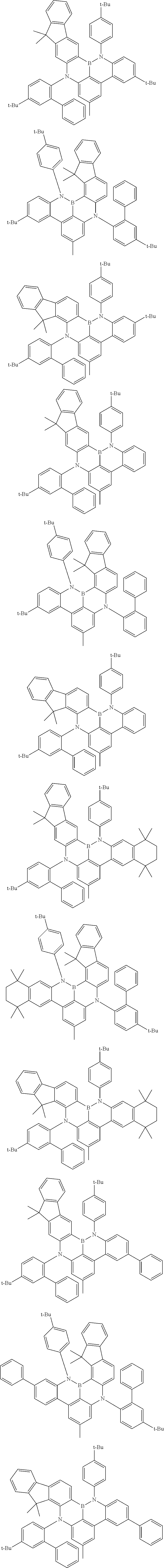 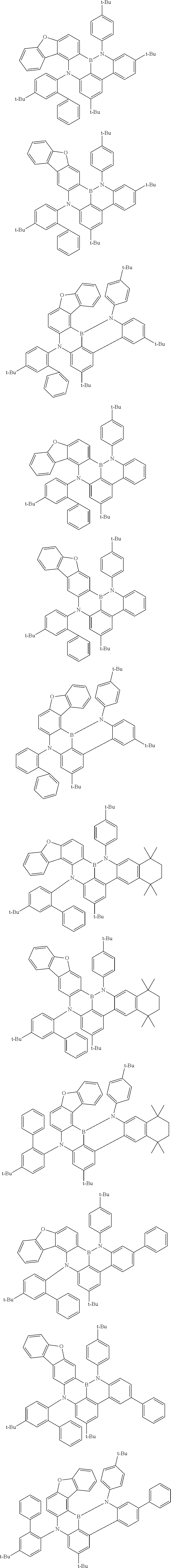 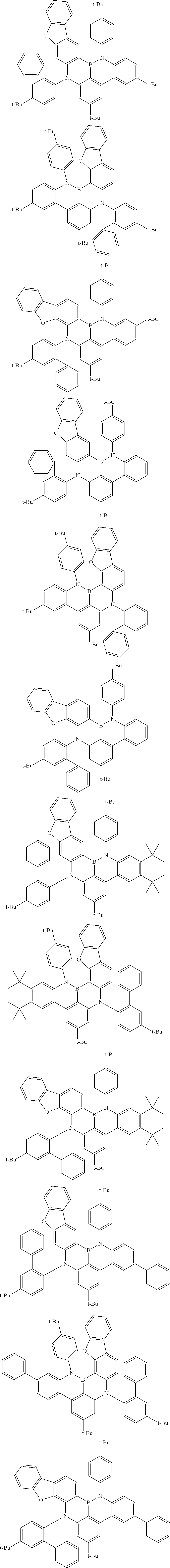 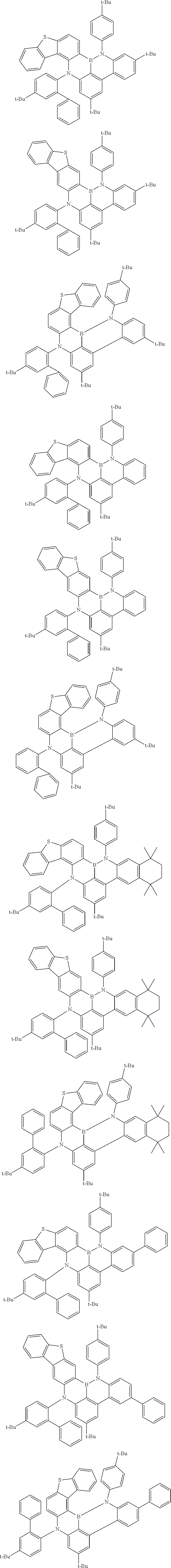 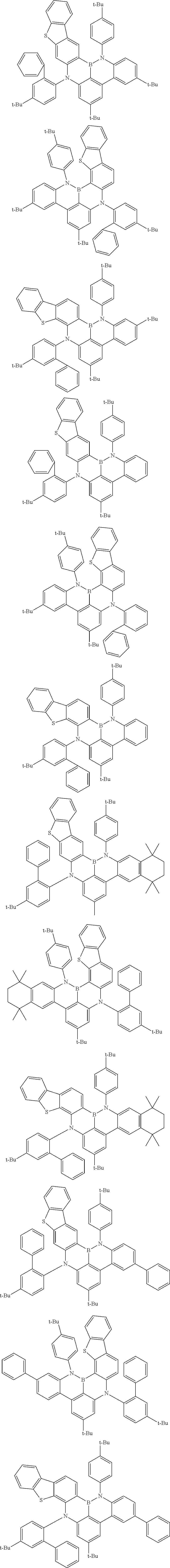 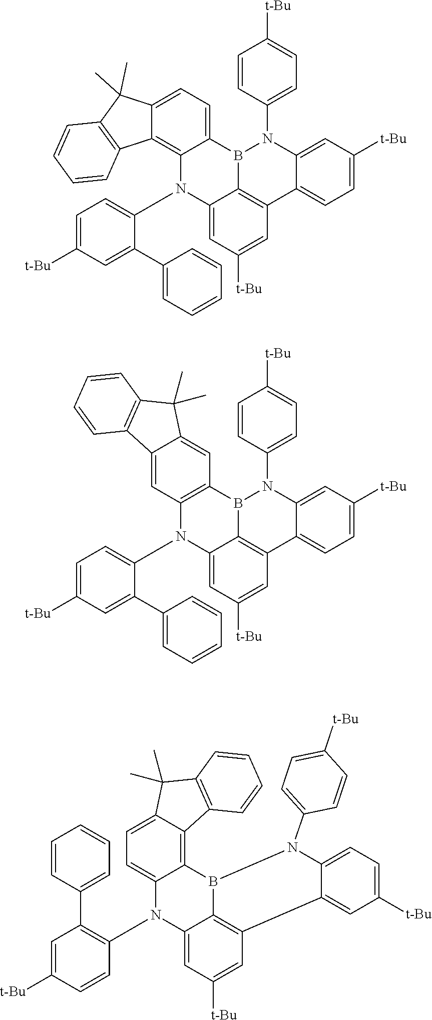 [SMILES: CC(C)(C)c1ccc(N2B3c4ccc5c(c4N(c4ccc(C(C)(C)C)cc4-c4ccccc4)c4cc(C(C)(C)C)cc(c43)-c3ccc(C(C)(C)C)cc32)-c2ccccc2C5(C)C)cc1 ; CC(C)(C)c1ccc(N2B3c4cc5c(cc4N(c4ccc(C(C)(C)C)cc4-c4ccccc4)c4cc(C(C)(C)C)cc(c43)-c3ccc(C(C)(C)C)cc32)-c2ccccc2C5(C)C)cc1 ; CC(C)(C)c1ccc(N2B3c4c(cc(C(C)(C)C)cc4N(c4ccc(C(C)(C)C)cc4-c4ccccc4)c4ccc5c(c43)-c3ccccc3C5(C)C)-c3cc(C(C)(C)C)ccc32)cc1] 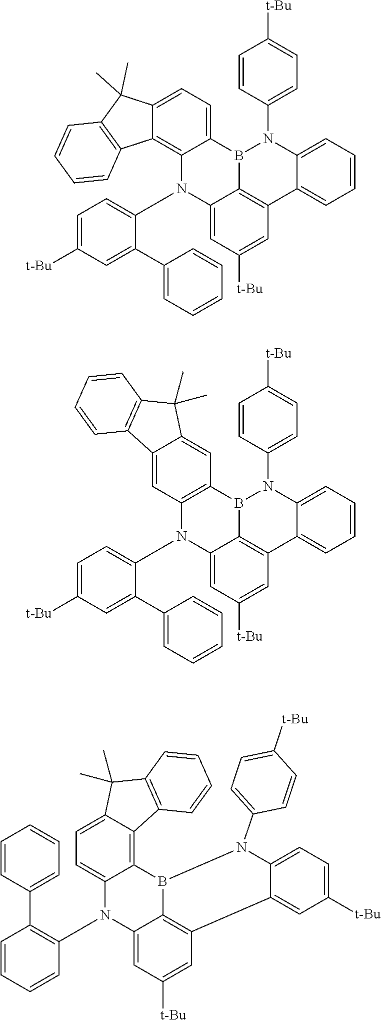 [SMILES: CC(C)(C)c1ccc(N2B3c4ccc5c(c4N(c4ccc(C(C)(C)C)cc4-c4ccccc4)c4cc(C(C)(C)C)cc(c43)-c3ccccc32)-c2ccccc2C5(C)C)cc1 ; CC(C)(C)c1ccc(N2B3c4cc5c(cc4N(c4ccc(C(C)(C)C)cc4-c4ccccc4)c4cc(C(C)(C)C)cc(c43)-c3ccccc32)-c2ccccc2C5(C)C)cc1 ; CC(C)(C)c1ccc(N2B3c4c(cc(C(C)(C)C)cc4N(c4ccccc4-c4ccccc4)c4ccc5c(c43)-c3ccccc3C5(C)C)-c3cc(C(C)(C)C)ccc32)cc1] 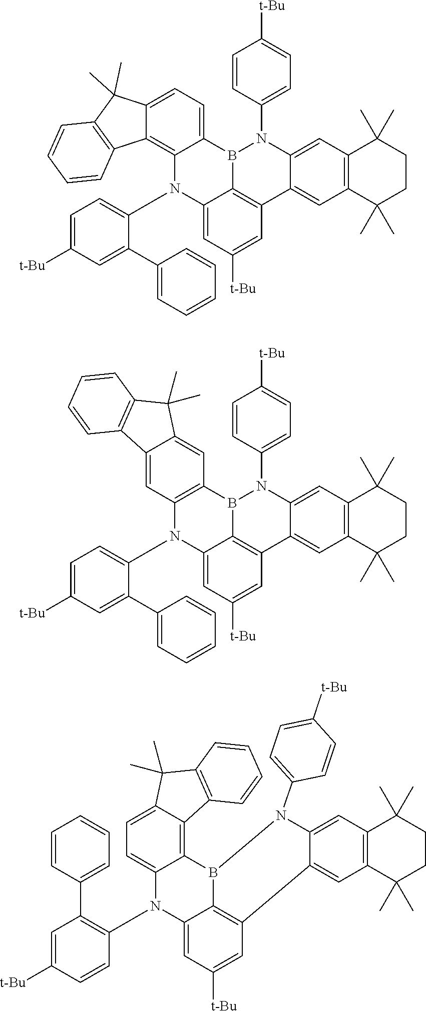 [SMILES: CC(C)(C)c1ccc(N2B3c4ccc5c(c4N(c4ccc(C(C)(C)C)cc4-c4ccccc4)c4cc(C(C)(C)C)cc(c43)-c3cc4c(cc32)C(C)(C)CCC4(C)C)-c2ccccc2C5(C)C)cc1 ; CC(C)(C)c1ccc(N2B3c4cc5c(cc4N(c4ccc(C(C)(C)C)cc4-c4ccccc4)c4cc(C(C)(C)C)cc(c43)-c3cc4c(cc32)C(C)(C)CCC4(C)C)-c2ccccc2C5(C)C)cc1 ; CC(C)(C)c1ccc(N2B3c4c(cc(C(C)(C)C)cc4N(c4ccc(C(C)(C)C)cc4-c4ccccc4)c4ccc5c(c43)-c3ccccc3C5(C)C)-c3cc4c(cc32)C(C)(C)CCC4(C)C)cc1] 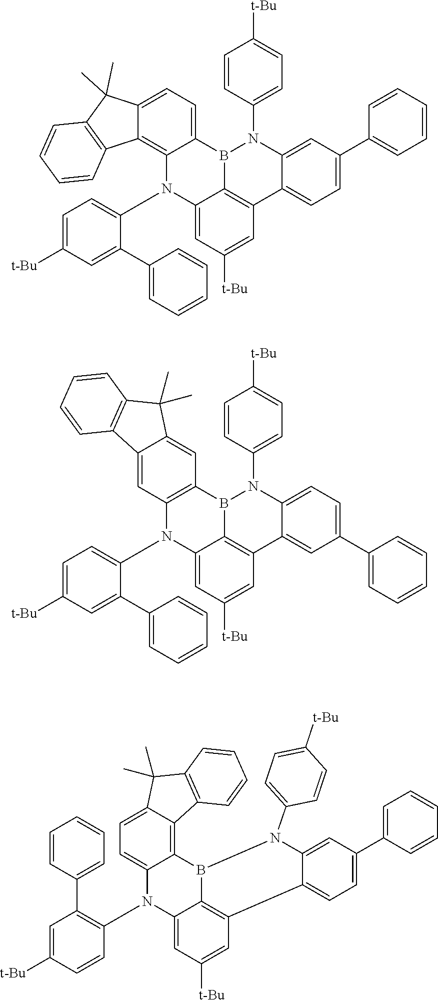 [SMILES: CC(C)(C)c1ccc(N2B3c4ccc5c(c4N(c4ccc(C(C)(C)C)cc4-c4ccccc4)c4cc(C(C)(C)C)cc(c43)-c3ccc(-c4ccccc4)cc32)-c2ccccc2C5(C)C)cc1 ; CC(C)(C)c1ccc(N2B3c4cc5c(cc4N(c4ccc(C(C)(C)C)cc4-c4ccccc4)c4cc(C(C)(C)C)cc(c43)-c3cc(-c4ccccc4)ccc32)-c2ccccc2C5(C)C)cc1 ; CC(C)(C)c1ccc(N2B3c4c(cc(C(C)(C)C)cc4N(c4ccc(C(C)(C)C)cc4-c4ccccc4)c4ccc5c(c43)-c3ccccc3C5(C)C)-c3ccc(-c4ccccc4)cc32)cc1] 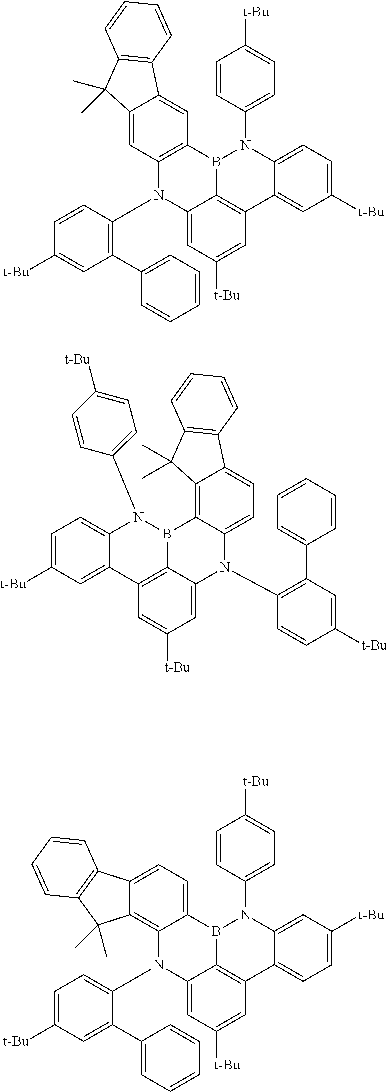 [SMILES: CC(C)(C)c1ccc(N2B3c4cc5c(cc4N(c4ccc(C(C)(C)C)cc4-c4ccccc4)c4cc(C(C)(C)C)cc(c43)-c3cc(C(C)(C)C)ccc32)C(C)(C)c2ccccc2-5)cc1 ; CC(C)(C)c1ccc(N2B3c4c(cc(C(C)(C)C)cc4N(c4ccc(C(C)(C)C)cc4-c4ccccc4)c4ccc5c(c43)C(C)(C)c3ccccc3-5)-c3cc(C(C)(C)C)ccc32)cc1 ; CC(C)(C)c1ccc(N2B3c4ccc5c(c4N(c4ccc(C(C)(C)C)cc4-c4ccccc4)c4cc(C(C)(C)C)cc(c43)-c3ccc(C(C)(C)C)cc32)C(C)(C)c2ccccc2-5)cc1] 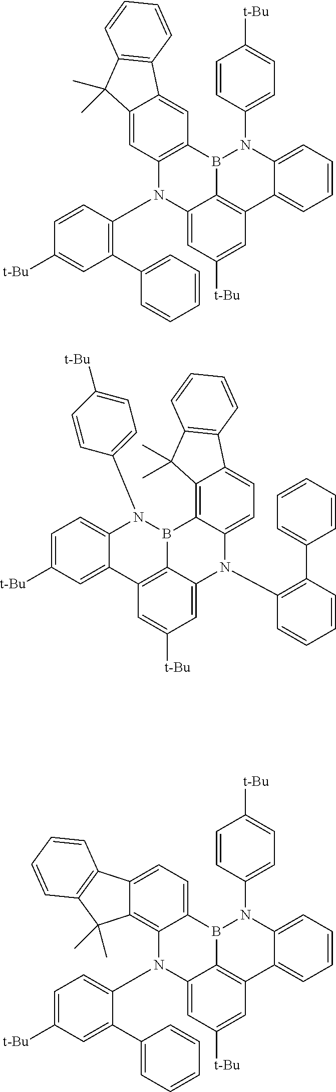 [SMILES: CC(C)(C)c1ccc(N2B3c4cc5c(cc4N(c4ccc(C(C)(C)C)cc4-c4ccccc4)c4cc(C(C)(C)C)cc(c43)-c3ccccc32)C(C)(C)c2ccccc2-5)cc1 ; CC(C)(C)c1ccc(N2B3c4c(cc(C(C)(C)C)cc4N(c4ccccc4-c4ccccc4)c4ccc5c(c43)C(C)(C)c3ccccc3-5)-c3cc(C(C)(C)C)ccc32)cc1 ; CC(C)(C)c1ccc(N2B3c4ccc5c(c4N(c4ccc(C(C)(C)C)cc4-c4ccccc4)c4cc(C(C)(C)C)cc(c43)-c3ccccc32)C(C)(C)c2ccccc2-5)cc1] 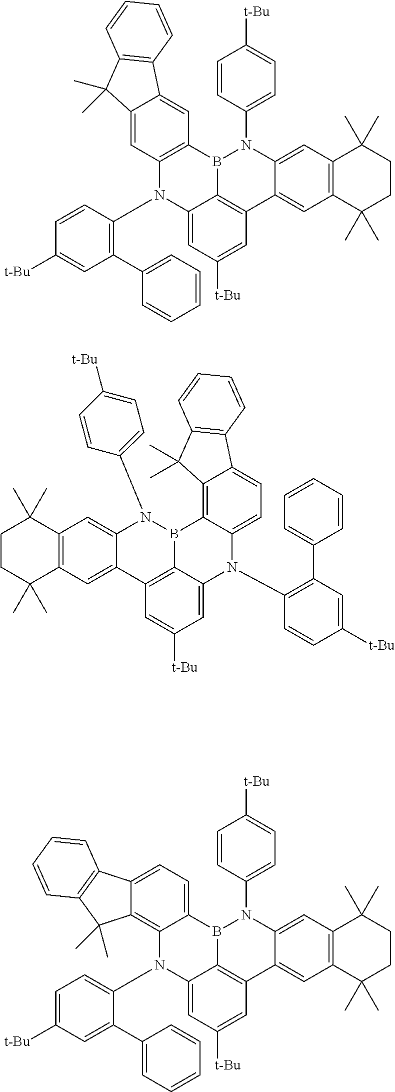 [SMILES: CC(C)(C)c1ccc(N2B3c4cc5c(cc4N(c4ccc(C(C)(C)C)cc4-c4ccccc4)c4cc(C(C)(C)C)cc(c43)-c3cc4c(cc32)C(C)(C)CCC4(C)C)C(C)(C)c2ccccc2-5)cc1 ; CC(C)(C)c1ccc(N2B3c4c(cc(C(C)(C)C)cc4N(c4ccc(C(C)(C)C)cc4-c4ccccc4)c4ccc5c(c43)C(C)(C)c3ccccc3-5)-c3cc4c(cc32)C(C)(C)CCC4(C)C)cc1 ; CC(C)(C)c1ccc(N2B3c4ccc5c(c4N(c4ccc(C(C)(C)C)cc4-c4ccccc4)c4cc(C(C)(C)C)cc(c43)-c3cc4c(cc32)C(C)(C)CCC4(C)C)C(C)(C)c2ccccc2-5)cc1] 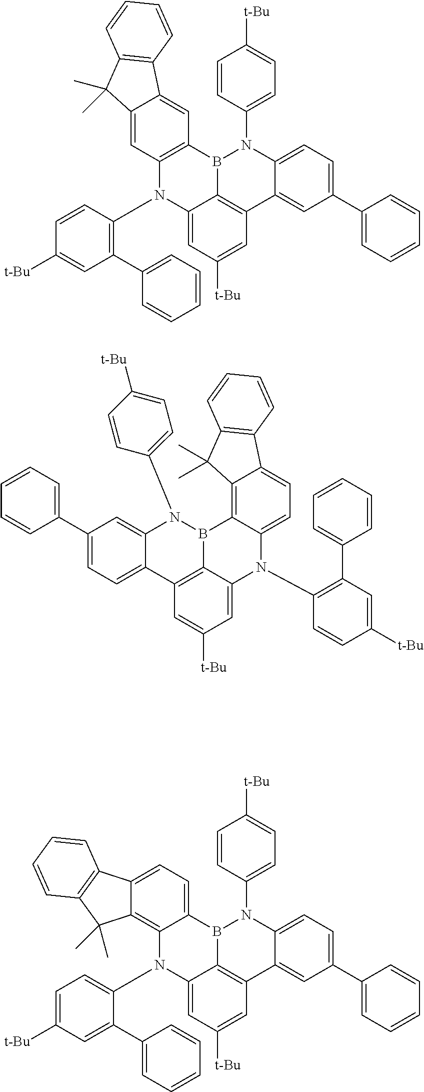 [SMILES: CC(C)(C)c1ccc(N2B3c4cc5c(cc4N(c4ccc(C(C)(C)C)cc4-c4ccccc4)c4cc(C(C)(C)C)cc(c43)-c3cc(-c4ccccc4)ccc32)C(C)(C)c2ccccc2-5)cc1 ; CC(C)(C)c1ccc(N2B3c4c(cc(C(C)(C)C)cc4N(c4ccc(C(C)(C)C)cc4-c4ccccc4)c4ccc5c(c43)C(C)(C)c3ccccc3-5)-c3ccc(-c4ccccc4)cc32)cc1 ; CC(C)(C)c1ccc(N2B3c4ccc5c(c4N(c4ccc(C(C)(C)C)cc4-c4ccccc4)c4cc(C(C)(C)C)cc(c43)-c3cc(-c4ccccc4)ccc32)C(C)(C)c2ccccc2-5)cc1] 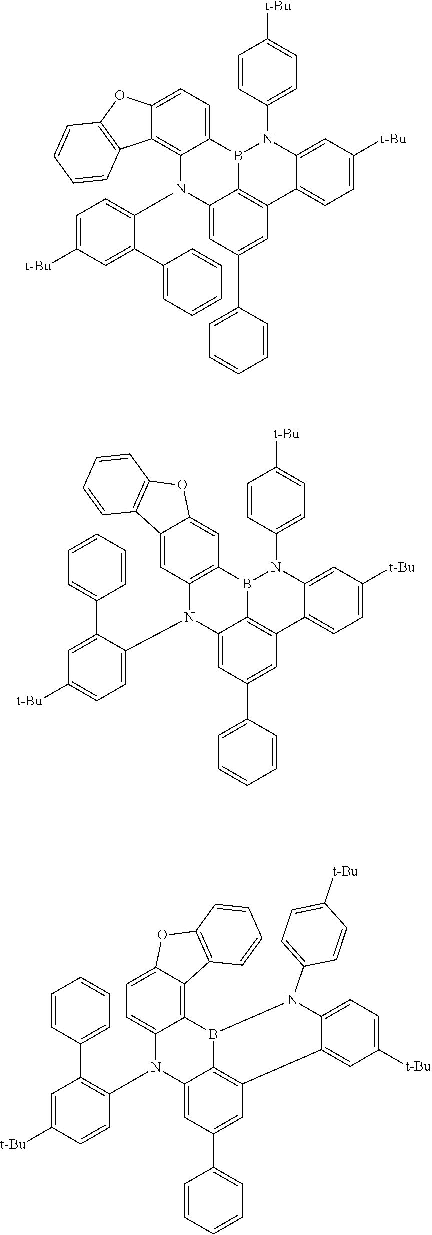 [SMILES: CC(C)(C)c1ccc(N2B3c4ccc5oc6ccccc6c5c4N(c4ccc(C(C)(C)C)cc4-c4ccccc4)c4cc(-c5ccccc5)cc(c43)-c3ccc(C(C)(C)C)cc32)cc1 ; CC(C)(C)c1ccc(N2B3c4cc5oc6ccccc6c5cc4N(c4ccc(C(C)(C)C)cc4-c4ccccc4)c4cc(-c5ccccc5)cc(c43)-c3ccc(C(C)(C)C)cc32)cc1 ; CC(C)(C)c1ccc(N2B3c4c(cc(-c5ccccc5)cc4N(c4ccc(C(C)(C)C)cc4-c4ccccc4)c4ccc5oc6ccccc6c5c43)-c3cc(C(C)(C)C)ccc32)cc1] 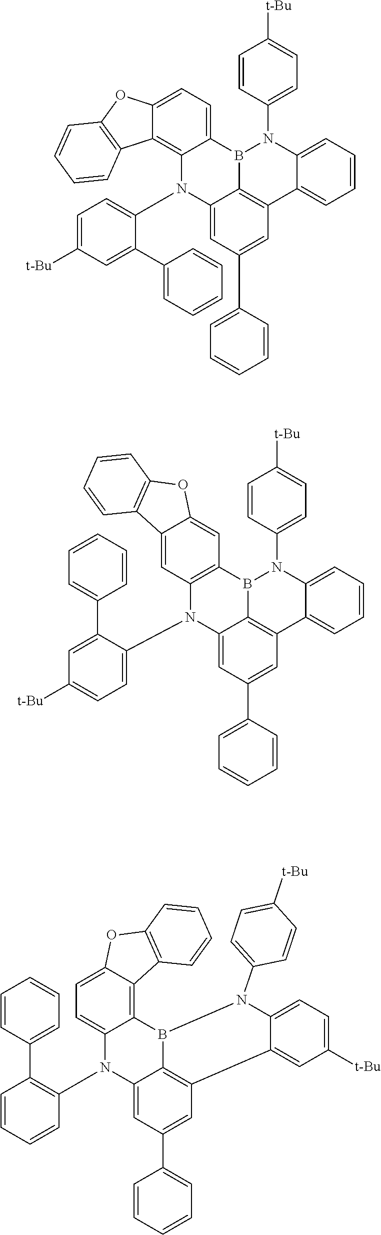 [SMILES: CC(C)(C)c1ccc(N2B3c4ccc5oc6ccccc6c5c4N(c4ccc(C(C)(C)C)cc4-c4ccccc4)c4cc(-c5ccccc5)cc(c43)-c3ccccc32)cc1 ; CC(C)(C)c1ccc(N2B3c4cc5oc6ccccc6c5cc4N(c4ccc(C(C)(C)C)cc4-c4ccccc4)c4cc(-c5ccccc5)cc(c43)-c3ccccc32)cc1 ; CC(C)(C)c1ccc(N2B3c4c(cc(-c5ccccc5)cc4N(c4ccccc4-c4ccccc4)c4ccc5oc6ccccc6c5c43)-c3cc(C(C)(C)C)ccc32)cc1] 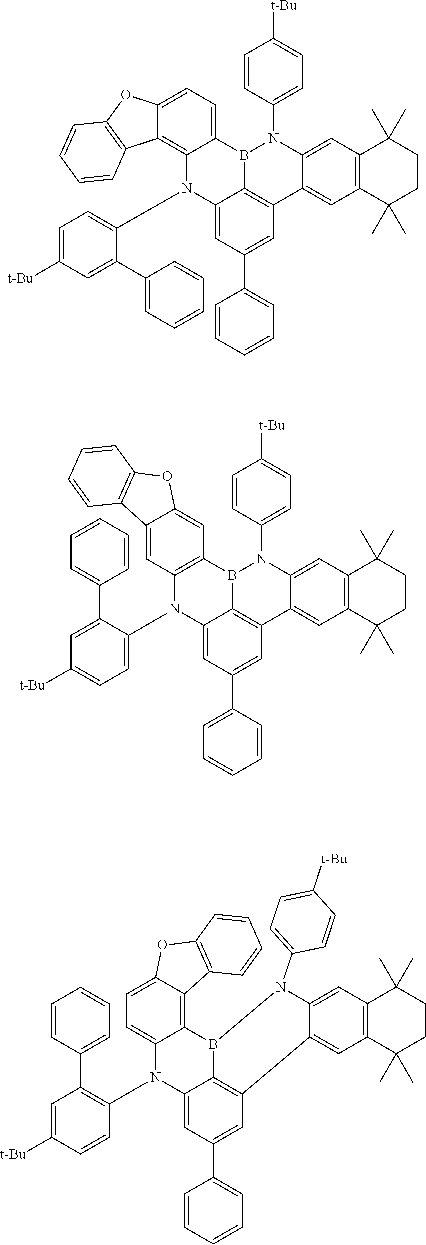 [SMILES: CC(C)(C)c1ccc(N2B3c4ccc5oc6ccccc6c5c4N(c4ccc(C(C)(C)C)cc4-c4ccccc4)c4cc(-c5ccccc5)cc(c43)-c3cc4c(cc32)C(C)(C)CCC4(C)C)cc1 ; CC(C)(C)c1ccc(N2B3c4cc5oc6ccccc6c5cc4N(c4ccc(C(C)(C)C)cc4-c4ccccc4)c4cc(-c5ccccc5)cc(c43)-c3cc4c(cc32)C(C)(C)CCC4(C)C)cc1 ; CC(C)(C)c1ccc(N2B3c4c(cc(-c5ccccc5)cc4N(c4ccc(C(C)(C)C)cc4-c4ccccc4)c4ccc5oc6ccccc6c5c43)-c3cc4c(cc32)C(C)(C)CCC4(C)C)cc1] 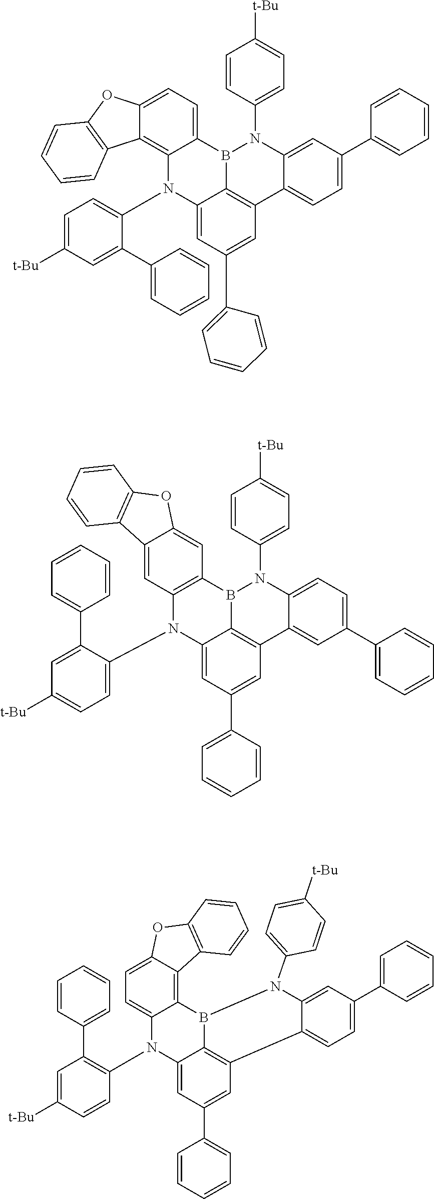 [SMILES: CC(C)(C)c1ccc(N2B3c4ccc5oc6ccccc6c5c4N(c4ccc(C(C)(C)C)cc4-c4ccccc4)c4cc(-c5ccccc5)cc(c43)-c3ccc(-c4ccccc4)cc32)cc1 ; CC(C)(C)c1ccc(N2B3c4cc5oc6ccccc6c5cc4N(c4ccc(C(C)(C)C)cc4-c4ccccc4)c4cc(-c5ccccc5)cc(c43)-c3cc(-c4ccccc4)ccc32)cc1 ; CC(C)(C)c1ccc(N2B3c4c(cc(-c5ccccc5)cc4N(c4ccc(C(C)(C)C)cc4-c4ccccc4)c4ccc5oc6ccccc6c5c43)-c3ccc(-c4ccccc4)cc32)cc1] 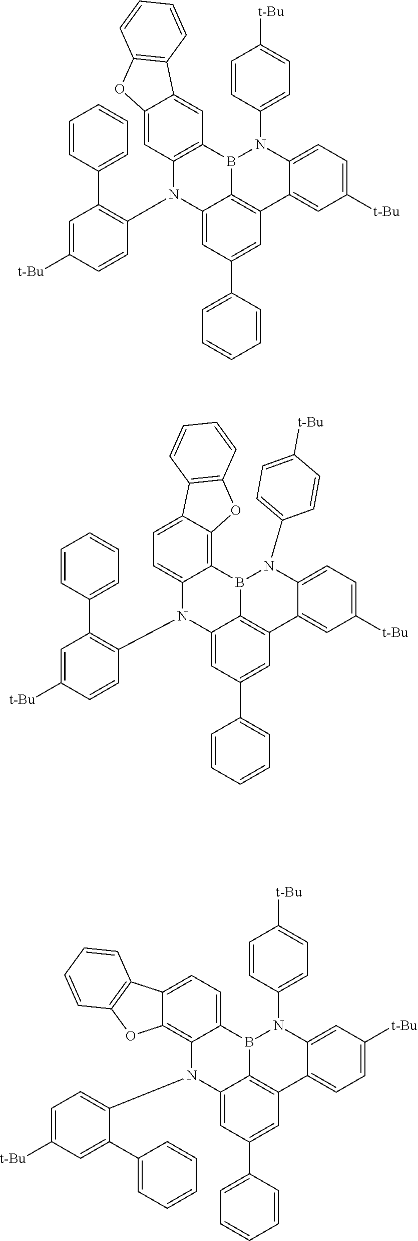 [SMILES: CC(C)(C)c1ccc(N2B3c4cc5c(cc4N(c4ccc(C(C)(C)C)cc4-c4ccccc4)c4cc(-c6ccccc6)cc(c43)-c3cc(C(C)(C)C)ccc32)oc2ccccc25)cc1 ; CC(C)(C)c1ccc(N2B3c4c(cc(-c5ccccc5)cc4N(c4ccc(C(C)(C)C)cc4-c4ccccc4)c4ccc5c(oc6ccccc65)c43)-c3cc(C(C)(C)C)ccc32)cc1 ; CC(C)(C)c1ccc(N2B3c4ccc5c(oc6ccccc65)c4N(c4ccc(C(C)(C)C)cc4-c4ccccc4)c4cc(-c5ccccc5)cc(c43)-c3ccc(C(C)(C)C)cc32)cc1] 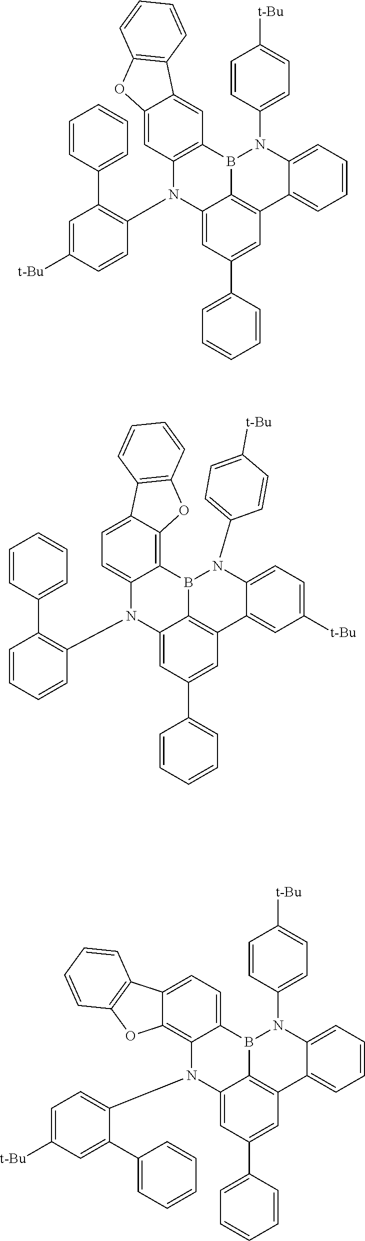 [SMILES: CC(C)(C)c1ccc(N2B3c4cc5c(cc4N(c4ccc(C(C)(C)C)cc4-c4ccccc4)c4cc(-c6ccccc6)cc(c43)-c3ccccc32)oc2ccccc25)cc1 ; CC(C)(C)c1ccc(N2B3c4c(cc(-c5ccccc5)cc4N(c4ccccc4-c4ccccc4)c4ccc5c(oc6ccccc65)c43)-c3cc(C(C)(C)C)ccc32)cc1 ; CC(C)(C)c1ccc(N2B3c4ccc5c(oc6ccccc65)c4N(c4ccc(C(C)(C)C)cc4-c4ccccc4)c4cc(-c5ccccc5)cc(c43)-c3ccccc32)cc1] 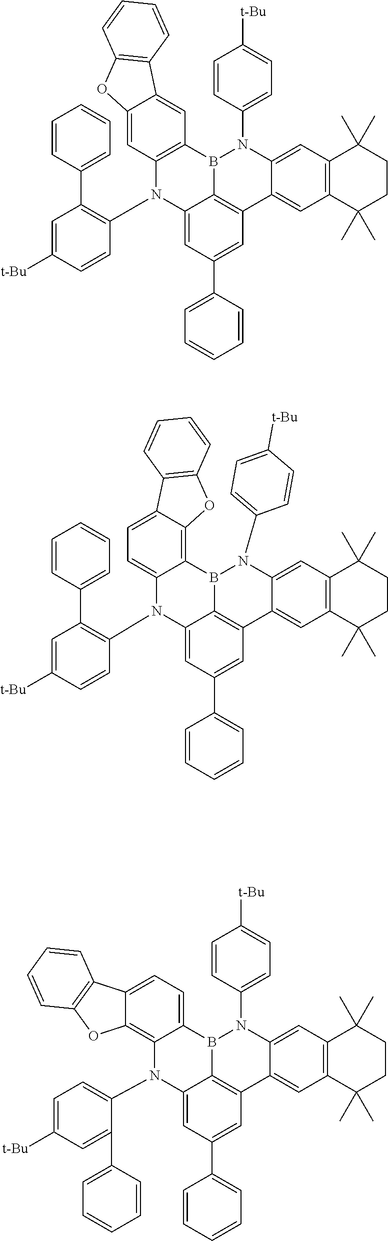 [SMILES: CC(C)(C)c1ccc(N2B3c4cc5c(cc4N(c4ccc(C(C)(C)C)cc4-c4ccccc4)c4cc(-c6ccccc6)cc(c43)-c3cc4c(cc32)C(C)(C)CCC4(C)C)oc2ccccc25)cc1 ; CC(C)(C)c1ccc(N2B3c4c(cc(-c5ccccc5)cc4N(c4ccc(C(C)(C)C)cc4-c4ccccc4)c4ccc5c(oc6ccccc65)c43)-c3cc4c(cc32)C(C)(C)CCC4(C)C)cc1 ; CC(C)(C)c1ccc(N2B3c4ccc5c(oc6ccccc65)c4N(c4ccc(C(C)(C)C)cc4-c4ccccc4)c4cc(-c5ccccc5)cc(c43)-c3cc4c(cc32)C(C)(C)CCC4(C)C)cc1] 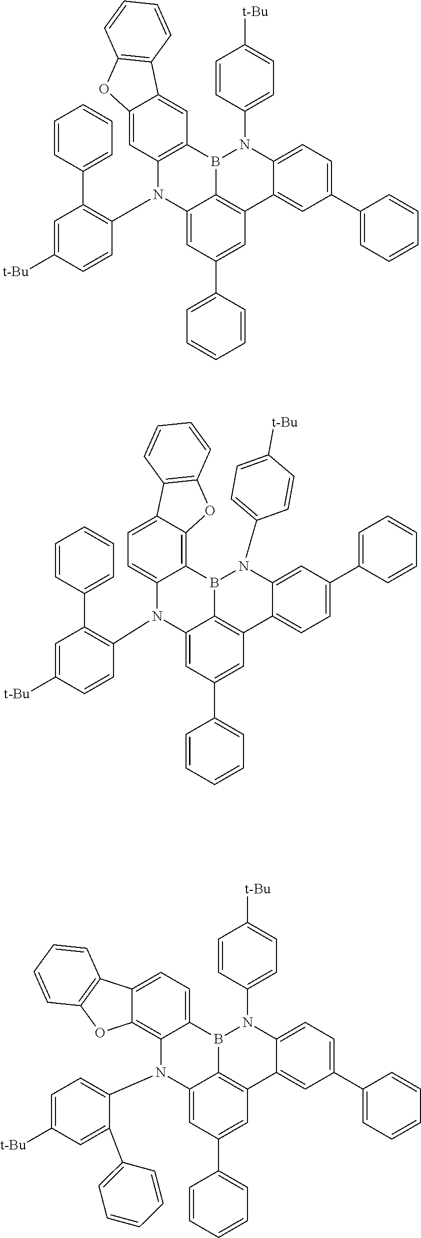 [SMILES: CC(C)(C)c1ccc(N2B3c4cc5c(cc4N(c4ccc(C(C)(C)C)cc4-c4ccccc4)c4cc(-c6ccccc6)cc(c43)-c3cc(-c4ccccc4)ccc32)oc2ccccc25)cc1 ; CC(C)(C)c1ccc(N2B3c4c(cc(-c5ccccc5)cc4N(c4ccc(C(C)(C)C)cc4-c4ccccc4)c4ccc5c(oc6ccccc65)c43)-c3ccc(-c4ccccc4)cc32)cc1 ; CC(C)(C)c1ccc(N2B3c4ccc5c(oc6ccccc65)c4N(c4ccc(C(C)(C)C)cc4-c4ccccc4)c4cc(-c5ccccc5)cc(c43)-c3cc(-c4ccccc4)ccc32)cc1] 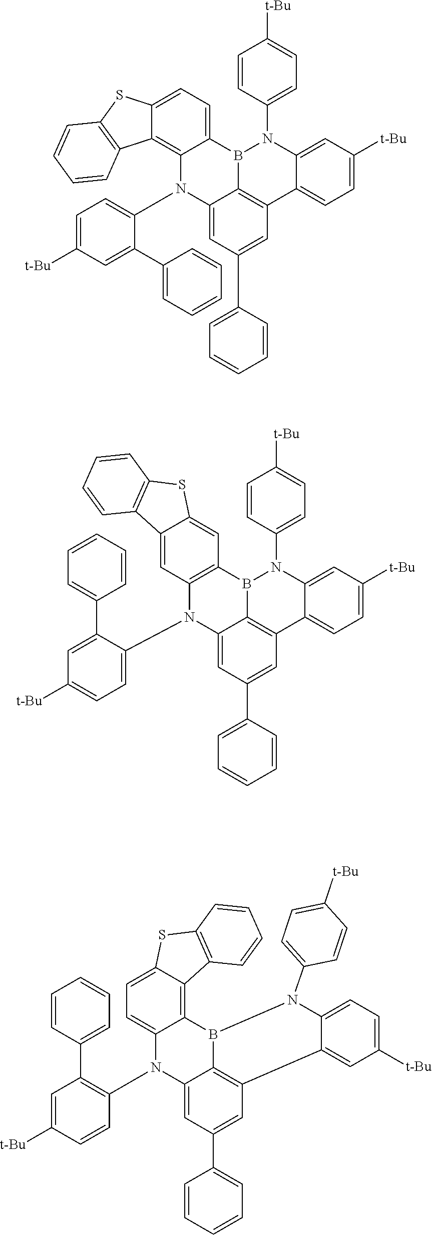 [SMILES: CC(C)(C)c1ccc(N2B3c4ccc5sc6ccccc6c5c4N(c4ccc(C(C)(C)C)cc4-c4ccccc4)c4cc(-c5ccccc5)cc(c43)-c3ccc(C(C)(C)C)cc32)cc1 ; CC(C)(C)c1ccc(N2B3c4cc5sc6ccccc6c5cc4N(c4ccc(C(C)(C)C)cc4-c4ccccc4)c4cc(-c5ccccc5)cc(c43)-c3ccc(C(C)(C)C)cc32)cc1 ; CC(C)(C)c1ccc(N2B3c4c(cc(-c5ccccc5)cc4N(c4ccc(C(C)(C)C)cc4-c4ccccc4)c4ccc5sc6ccccc6c5c43)-c3cc(C(C)(C)C)ccc32)cc1] 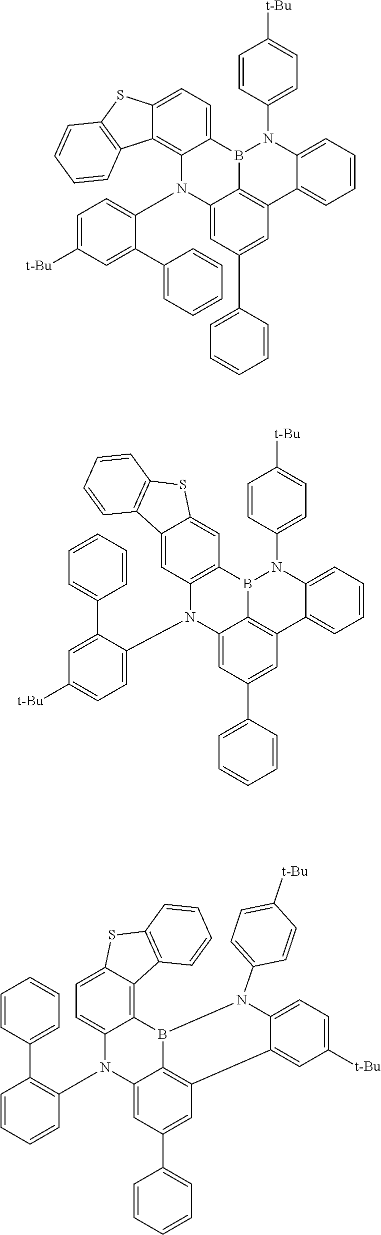 [SMILES: CC(C)(C)c1ccc(N2B3c4ccc5sc6ccccc6c5c4N(c4ccc(C(C)(C)C)cc4-c4ccccc4)c4cc(-c5ccccc5)cc(c43)-c3ccccc32)cc1 ; CC(C)(C)c1ccc(N2B3c4cc5sc6ccccc6c5cc4N(c4ccc(C(C)(C)C)cc4-c4ccccc4)c4cc(-c5ccccc5)cc(c43)-c3ccccc32)cc1 ; CC(C)(C)c1ccc(N2B3c4c(cc(-c5ccccc5)cc4N(c4ccccc4-c4ccccc4)c4ccc5sc6ccccc6c5c43)-c3cc(C(C)(C)C)ccc32)cc1] 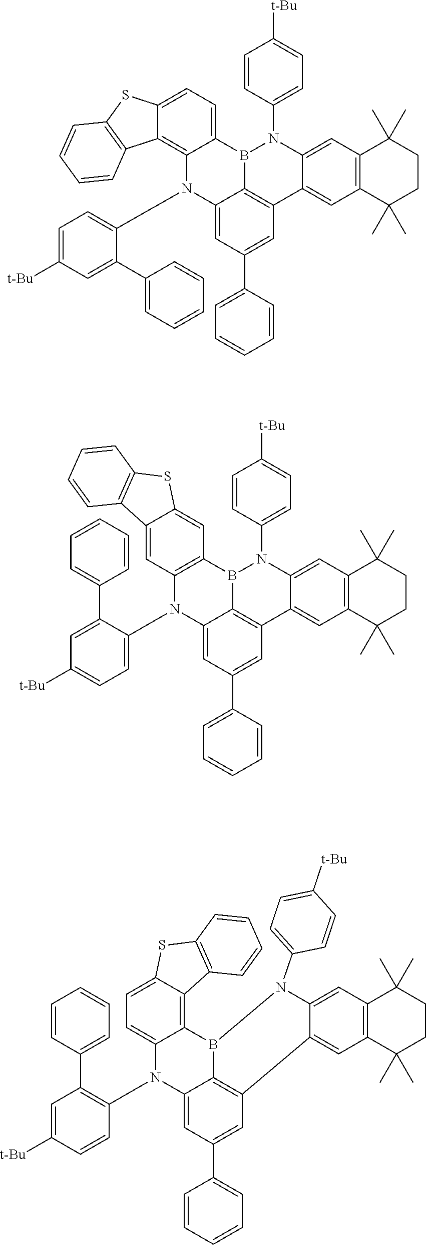 [SMILES: CC(C)(C)c1ccc(N2B3c4ccc5sc6ccccc6c5c4N(c4ccc(C(C)(C)C)cc4-c4ccccc4)c4cc(-c5ccccc5)cc(c43)-c3cc4c(cc32)C(C)(C)CCC4(C)C)cc1 ; CC(C)(C)c1ccc(N2B3c4cc5sc6ccccc6c5cc4N(c4ccc(C(C)(C)C)cc4-c4ccccc4)c4cc(-c5ccccc5)cc(c43)-c3cc4c(cc32)C(C)(C)CCC4(C)C)cc1 ; CC(C)(C)c1ccc(N2B3c4c(cc(-c5ccccc5)cc4N(c4ccc(C(C)(C)C)cc4-c4ccccc4)c4ccc5sc6ccccc6c5c43)-c3cc4c(cc32)C(C)(C)CCC4(C)C)cc1] 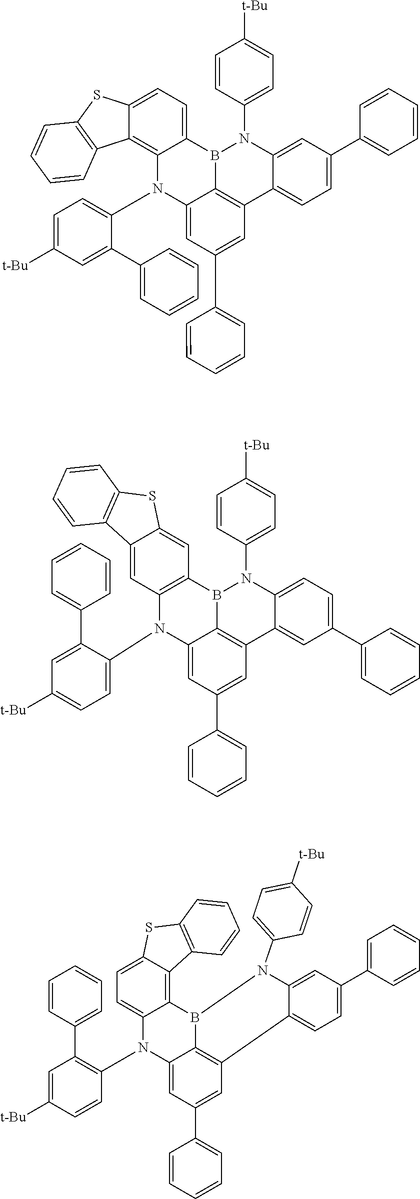 [SMILES: CC(C)(C)c1ccc(N2B3c4ccc5sc6ccccc6c5c4N(c4ccc(C(C)(C)C)cc4-c4ccccc4)c4cc(-c5ccccc5)cc(c43)-c3ccc(-c4ccccc4)cc32)cc1 ; CC(C)(C)c1ccc(N2B3c4cc5sc6ccccc6c5cc4N(c4ccc(C(C)(C)C)cc4-c4ccccc4)c4cc(-c5ccccc5)cc(c43)-c3cc(-c4ccccc4)ccc32)cc1 ; CC(C)(C)c1ccc(N2B3c4c(cc(-c5ccccc5)cc4N(c4ccc(C(C)(C)C)cc4-c4ccccc4)c4ccc5sc6ccccc6c5c43)-c3ccc(-c4ccccc4)cc32)cc1] 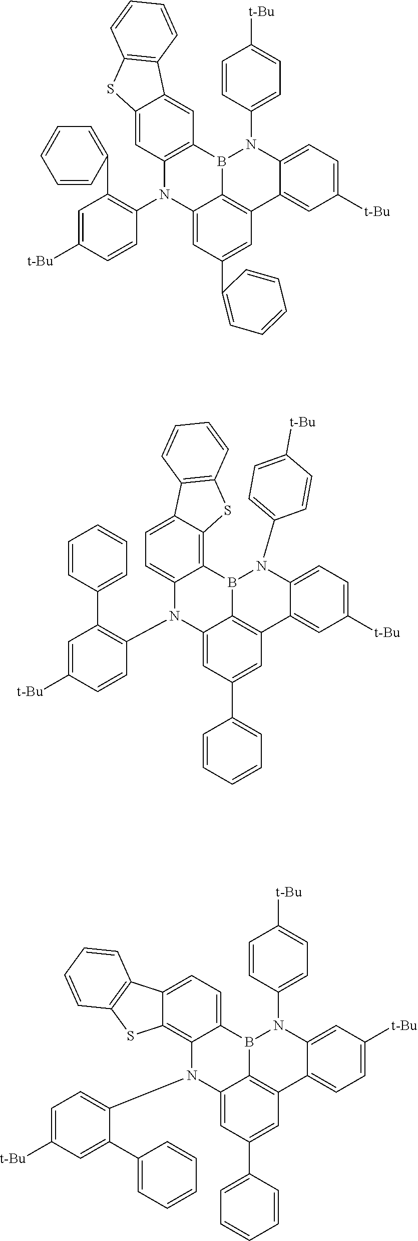 [SMILES: CC(C)(C)c1ccc(N2B3c4cc5c(cc4N(c4ccc(C(C)(C)C)cc4-c4ccccc4)c4cc(-c6ccccc6)cc(c43)-c3cc(C(C)(C)C)ccc32)sc2ccccc25)cc1 ; CC(C)(C)c1ccc(N2B3c4c(cc(-c5ccccc5)cc4N(c4ccc(C(C)(C)C)cc4-c4ccccc4)c4ccc5c(sc6ccccc65)c43)-c3cc(C(C)(C)C)ccc32)cc1 ; CC(C)(C)c1ccc(N2B3c4ccc5c(sc6ccccc65)c4N(c4ccc(C(C)(C)C)cc4-c4ccccc4)c4cc(-c5ccccc5)cc(c43)-c3ccc(C(C)(C)C)cc32)cc1] 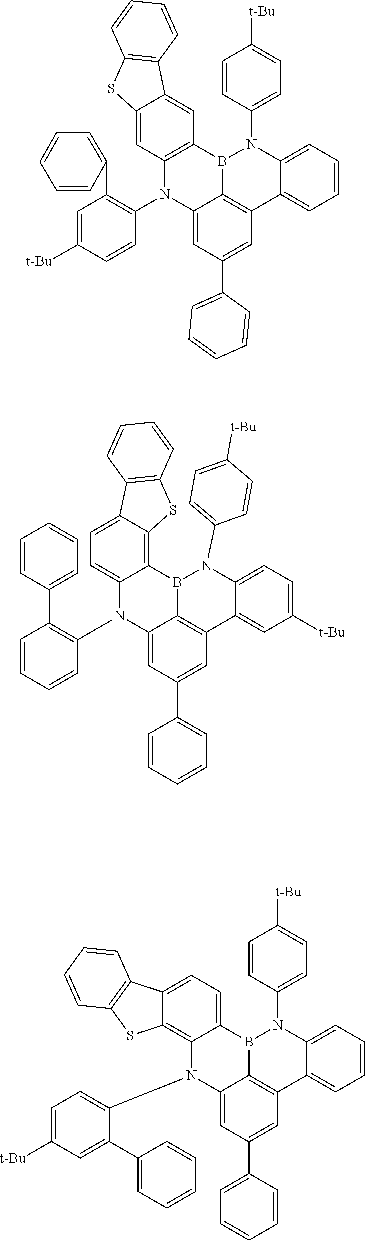 [SMILES: CC(C)(C)c1ccc(N2B3c4cc5c(cc4N(c4ccc(C(C)(C)C)cc4-c4ccccc4)c4cc(-c6ccccc6)cc(c43)-c3ccccc32)sc2ccccc25)cc1 ; CC(C)(C)c1ccc(N2B3c4c(cc(-c5ccccc5)cc4N(c4ccccc4-c4ccccc4)c4ccc5c(sc6ccccc65)c43)-c3cc(C(C)(C)C)ccc32)cc1 ; CC(C)(C)c1ccc(N2B3c4ccc5c(sc6ccccc65)c4N(c4ccc(C(C)(C)C)cc4-c4ccccc4)c4cc(-c5ccccc5)cc(c43)-c3ccccc32)cc1] 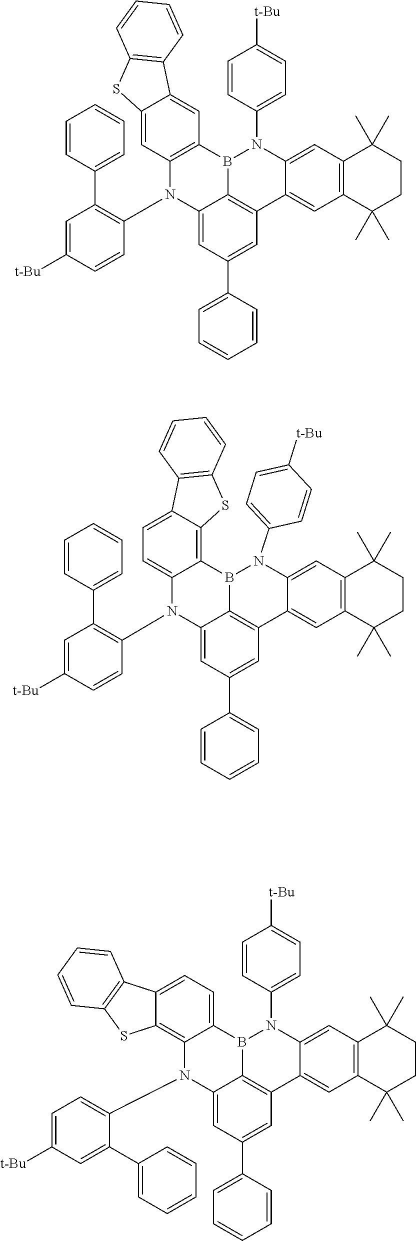 [SMILES: CC(C)(C)c1ccc(N2B3c4cc5c(cc4N(c4ccc(C(C)(C)C)cc4-c4ccccc4)c4cc(-c6ccccc6)cc(c43)-c3cc4c(cc32)C(C)(C)CCC4(C)C)sc2ccccc25)cc1 ; CC(C)(C)c1ccc(N2B3c4c(cc(-c5ccccc5)cc4N(c4ccc(C(C)(C)C)cc4-c4ccccc4)c4ccc5c(sc6ccccc65)c43)-c3cc4c(cc32)C(C)(C)CCC4(C)C)cc1 ; CC(C)(C)c1ccc(N2B3c4ccc5c(sc6ccccc65)c4N(c4ccc(C(C)(C)C)cc4-c4ccccc4)c4cc(-c5ccccc5)cc(c43)-c3cc4c(cc32)C(C)(C)CCC4(C)C)cc1] 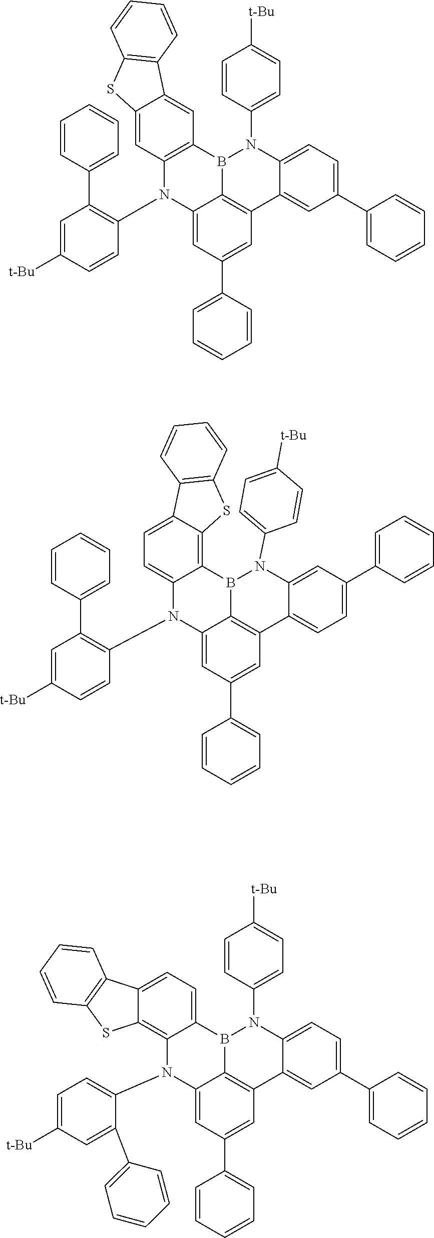 [SMILES: CC(C)(C)c1ccc(N2B3c4cc5c(cc4N(c4ccc(C(C)(C)C)cc4-c4ccccc4)c4cc(-c6ccccc6)cc(c43)-c3cc(-c4ccccc4)ccc32)sc2ccccc25)cc1 ; CC(C)(C)c1ccc(N2B3c4c(cc(-c5ccccc5)cc4N(c4ccc(C(C)(C)C)cc4-c4ccccc4)c4ccc5c(sc6ccccc65)c43)-c3ccc(-c4ccccc4)cc32)cc1 ; CC(C)(C)c1ccc(N2B3c4ccc5c(sc6ccccc65)c4N(c4ccc(C(C)(C)C)cc4-c4ccccc4)c4cc(-c5ccccc5)cc(c43)-c3cc(-c4ccccc4)ccc32)cc1] 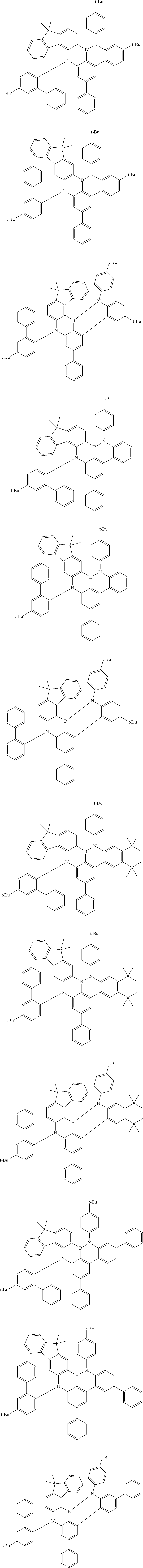 [chemical structure] 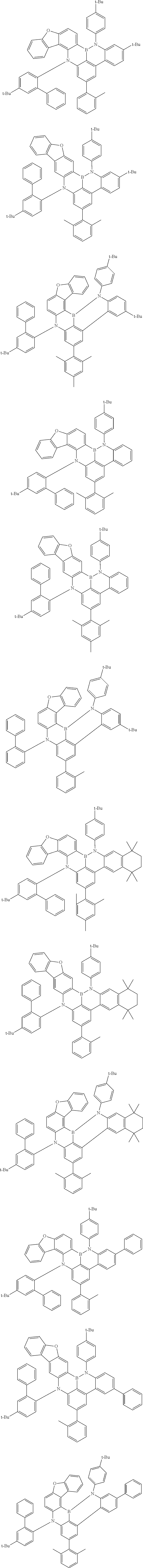 [chemical structure] 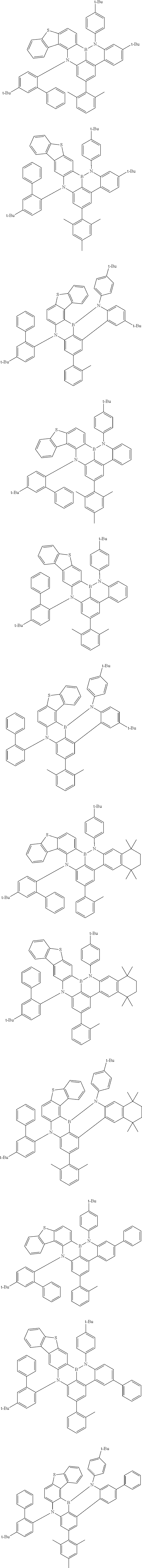 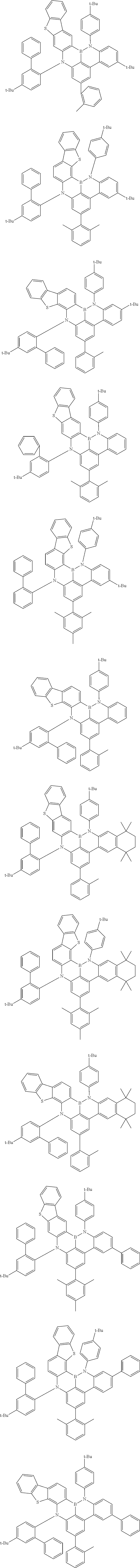 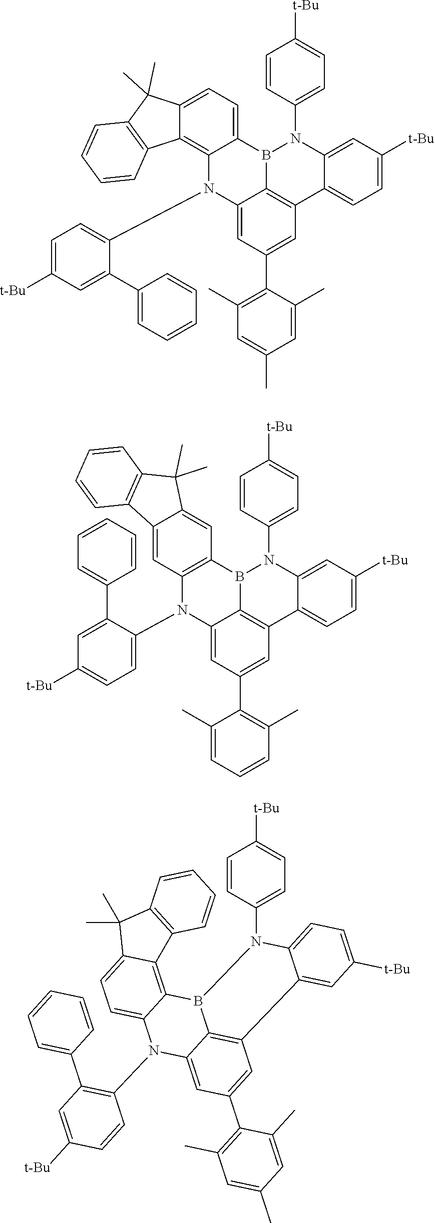 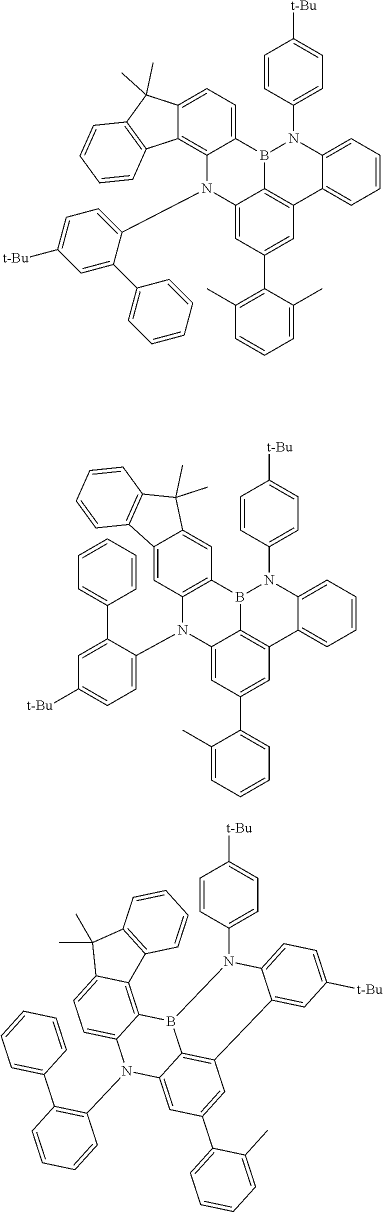 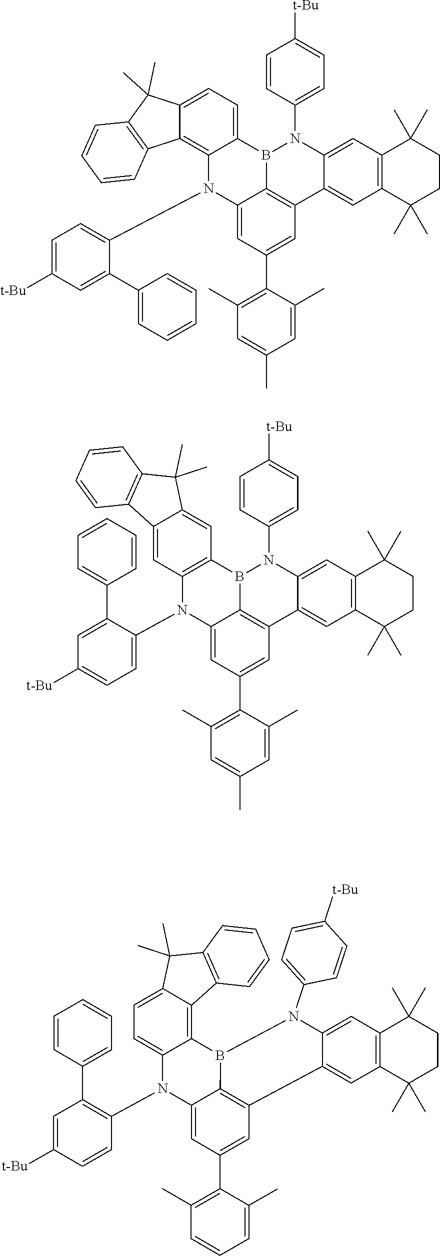 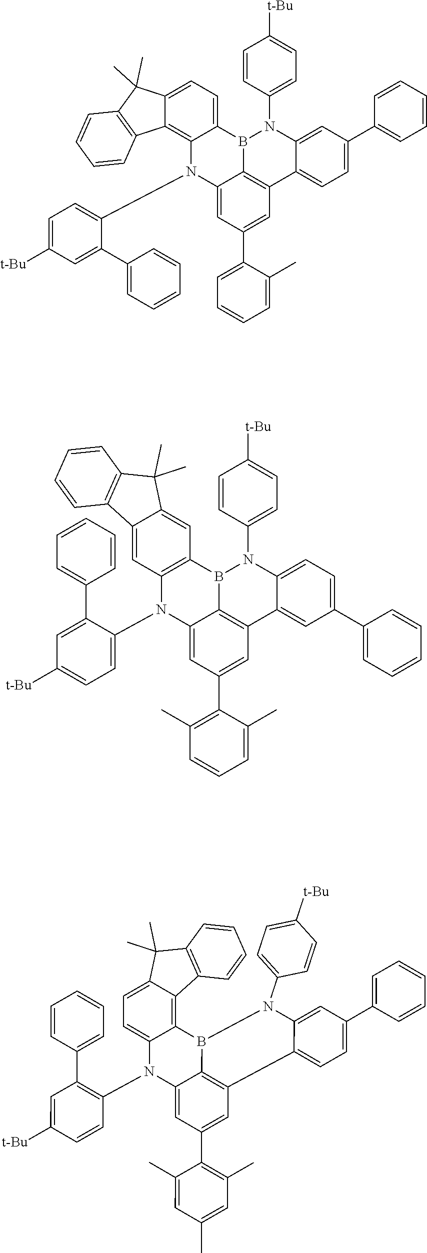 [SMILES: Cc1ccccc1-c1cc2c3c(c1)N(c1ccc(C(C)(C)C)cc1-c1ccccc1)c1c(ccc4c1-c1ccccc1C4(C)C)B3N(c1ccc(C(C)(C)C)cc1)c1cc(-c3ccccc3)ccc1-2 ; Cc1cccc(C)c1-c1cc2c3c(c1)N(c1ccc(C(C)(C)C)cc1-c1ccccc1)c1cc4c(cc1B3N(c1ccc(C(C)(C)C)cc1)c1ccc(-c3ccccc3)cc1-2)C(C)(C)c1ccccc1-4 ; Cc1cc(C)c(-c2cc3c4c(c2)N(c2ccc(C(C)(C)C)cc2-c2ccccc2)c2ccc5c(c2B4N(c2ccc(C(C)(C)C)cc2)c2cc(-c4ccccc4)ccc2-3)-c2ccccc2C5(C)C)c(C)c1] 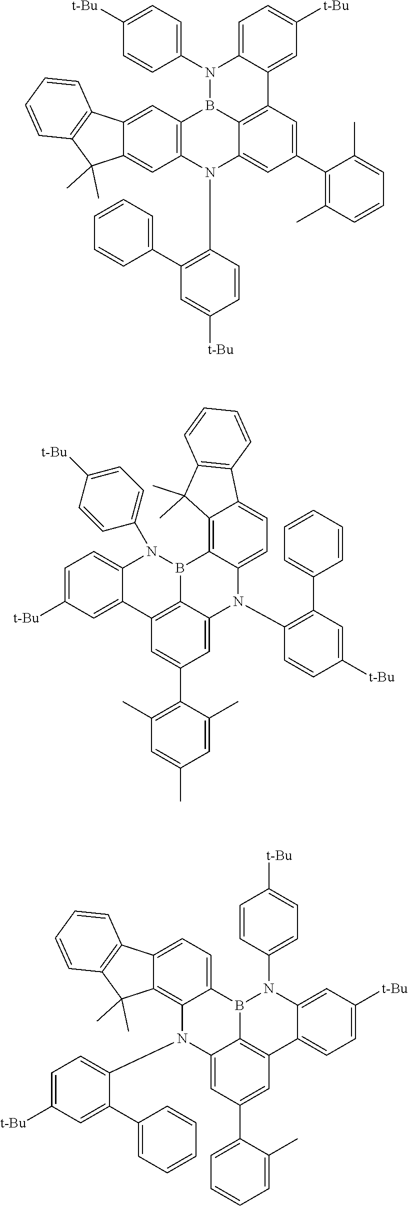 [SMILES: Cc1cccc(C)c1-c1cc2c3c(c1)N(c1ccc(C(C)(C)C)cc1-c1ccccc1)c1cc4c(cc1B3N(c1ccc(C(C)(C)C)cc1)c1ccc(C(C)(C)C)cc1-2)-c1ccccc1C4(C)C ; Cc1cc(C)c(-c2cc3c4c(c2)N(c2ccc(C(C)(C)C)cc2-c2ccccc2)c2ccc5c(c2B4N(c2ccc(C(C)(C)C)cc2)c2ccc(C(C)(C)C)cc2-3)C(C)(C)c2ccccc2-5)c(C)c1 ; Cc1ccccc1-c1cc2c3c(c1)N(c1ccc(C(C)(C)C)cc1-c1ccccc1)c1c(ccc4c1C(C)(C)c1ccccc1-4)B3N(c1ccc(C(C)(C)C)cc1)c1cc(C(C)(C)C)ccc1-2] 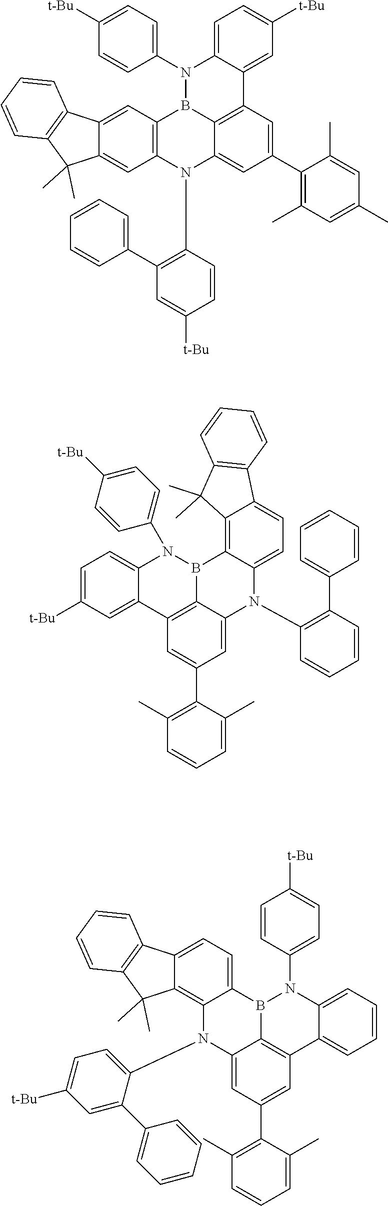 [SMILES: Cc1cc(C)c(-c2cc3c4c(c2)N(c2ccc(C(C)(C)C)cc2-c2ccccc2)c2cc5c(cc2B4N(c2ccc(C(C)(C)C)cc2)c2ccc(C(C)(C)C)cc2-3)-c2ccccc2C5(C)C)c(C)c1 ; Cc1cccc(C)c1-c1cc2c3c(c1)N(c1ccccc1-c1ccccc1)c1ccc4c(c1B3N(c1ccc(C(C)(C)C)cc1)c1ccc(C(C)(C)C)cc1-2)C(C)(C)c1ccccc1-4 ; Cc1cccc(C)c1-c1cc2c3c(c1)N(c1ccc(C(C)(C)C)cc1-c1ccccc1)c1c(ccc4c1C(C)(C)c1ccccc1-4)B3N(c1ccc(C(C)(C)C)cc1)c1ccccc1-2] 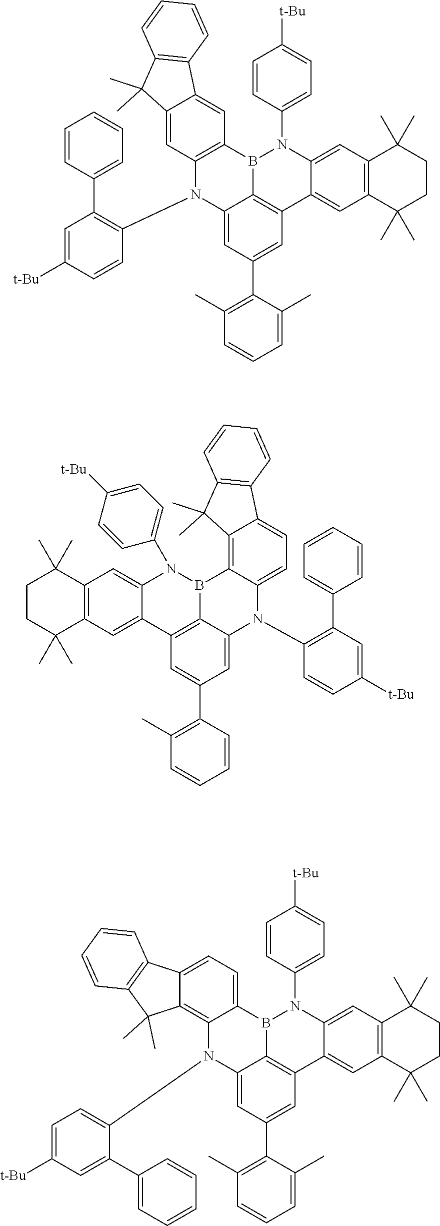 [SMILES: Cc1cccc(C)c1-c1cc2c3c(c1)N(c1ccc(C(C)(C)C)cc1-c1ccccc1)c1cc4c(cc1B3N(c1ccc(C(C)(C)C)cc1)c1cc3c(cc1-2)C(C)(C)CCC3(C)C)-c1ccccc1C4(C)C ; Cc1ccccc1-c1cc2c3c(c1)N(c1ccc(C(C)(C)C)cc1-c1ccccc1)c1ccc4c(c1B3N(c1ccc(C(C)(C)C)cc1)c1cc3c(cc1-2)C(C)(C)CCC3(C)C)C(C)(C)c1ccccc1-4 ; Cc1cccc(C)c1-c1cc2c3c(c1)N(c1ccc(C(C)(C)C)cc1-c1ccccc1)c1c(ccc4c1C(C)(C)c1ccccc1-4)B3N(c1ccc(C(C)(C)C)cc1)c1cc3c(cc1-2)C(C)(C)CCC3(C)C] 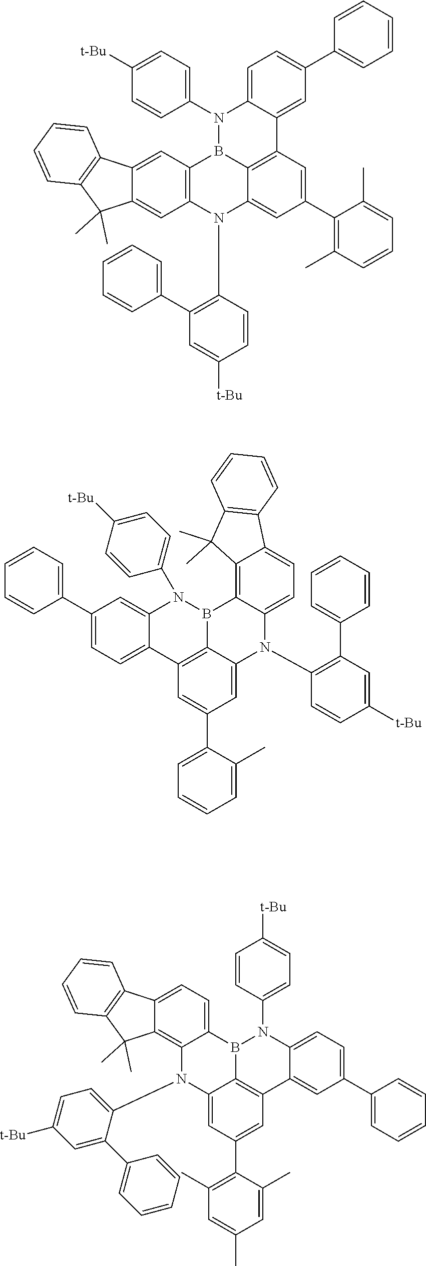 [SMILES: Cc1cccc(C)c1-c1cc2c3c(c1)N(c1ccc(C(C)(C)C)cc1-c1ccccc1)c1cc4c(cc1B3N(c1ccc(C(C)(C)C)cc1)c1ccc(-c3ccccc3)cc1-2)-c1ccccc1C4(C)C ; Cc1ccccc1-c1cc2c3c(c1)N(c1ccc(C(C)(C)C)cc1-c1ccccc1)c1ccc4c(c1B3N(c1ccc(C(C)(C)C)cc1)c1cc(-c3ccccc3)ccc1-2)C(C)(C)c1ccccc1-4 ; Cc1cc(C)c(-c2cc3c4c(c2)N(c2ccc(C(C)(C)C)cc2-c2ccccc2)c2c(ccc5c2C(C)(C)c2ccccc2-5)B4N(c2ccc(C(C)(C)C)cc2)c2ccc(-c4ccccc4)cc2-3)c(C)c1] 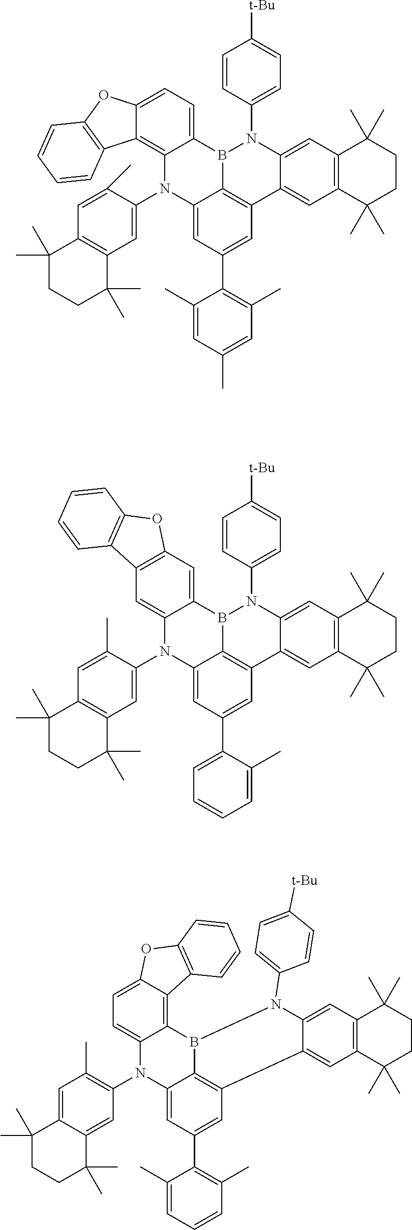 [SMILES: Cc1cc(C)c(-c2cc3c4c(c2)N(c2cc5c(cc2C)C(C)(C)CCC5(C)C)c2c(ccc5oc6ccccc6c25)B4N(c2ccc(C(C)(C)C)cc2)c2cc4c(cc2-3)C(C)(C)CCC4(C)C)c(C)c1 ; Cc1ccccc1-c1cc2c3c(c1)N(c1cc4c(cc1C)C(C)(C)CCC4(C)C)c1cc4c(cc1B3N(c1ccc(C(C)(C)C)cc1)c1cc3c(cc1-2)C(C)(C)CCC3(C)C)oc1ccccc14 ; Cc1cc2c(cc1N1c3cc(-c4c(C)cccc4C)cc4c3B(c3c1ccc1oc5ccccc5c31)N(c1ccc(C(C)(C)C)cc1)c1cc3c(cc1-4)C(C)(C)CCC3(C)C)C(C)(C)CCC2(C)C] 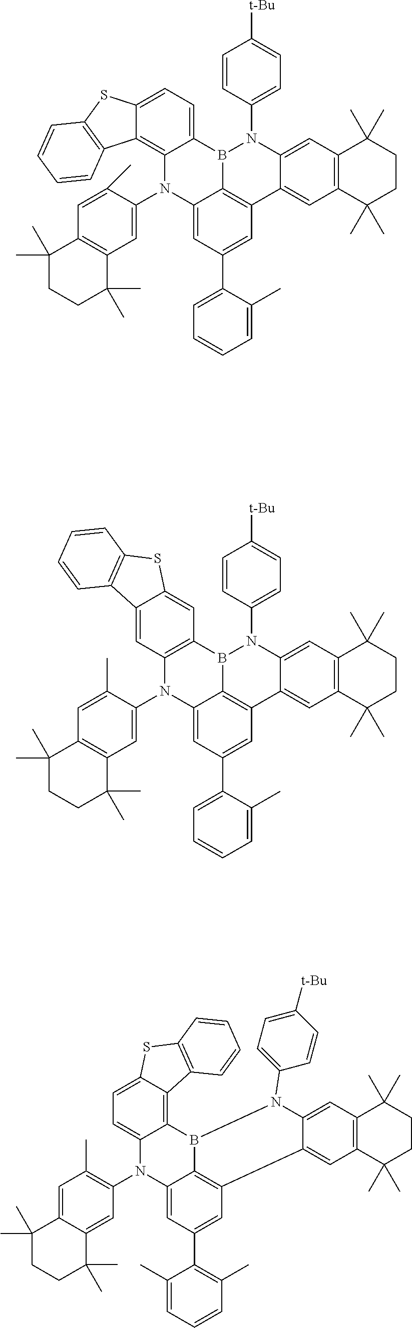 [SMILES: Cc1ccccc1-c1cc2c3c(c1)N(c1cc4c(cc1C)C(C)(C)CCC4(C)C)c1c(ccc4sc5ccccc5c14)B3N(c1ccc(C(C)(C)C)cc1)c1cc3c(cc1-2)C(C)(C)CCC3(C)C ; Cc1ccccc1-c1cc2c3c(c1)N(c1cc4c(cc1C)C(C)(C)CCC4(C)C)c1cc4c(cc1B3N(c1ccc(C(C)(C)C)cc1)c1cc3c(cc1-2)C(C)(C)CCC3(C)C)sc1ccccc14 ; Cc1cc2c(cc1N1c3cc(-c4c(C)cccc4C)cc4c3B(c3c1ccc1sc5ccccc5c31)N(c1ccc(C(C)(C)C)cc1)c1cc3c(cc1-4)C(C)(C)CCC3(C)C)C(C)(C)CCC2(C)C] 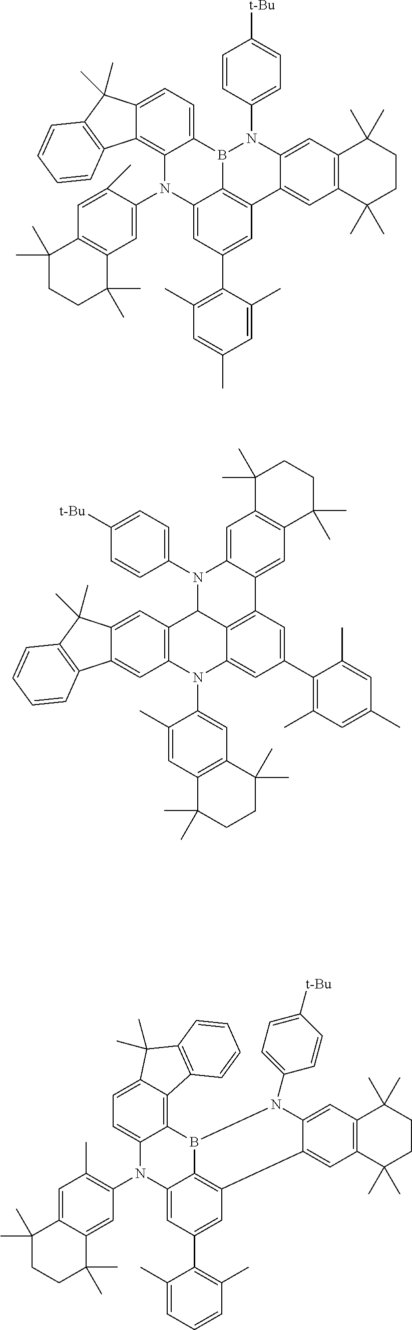 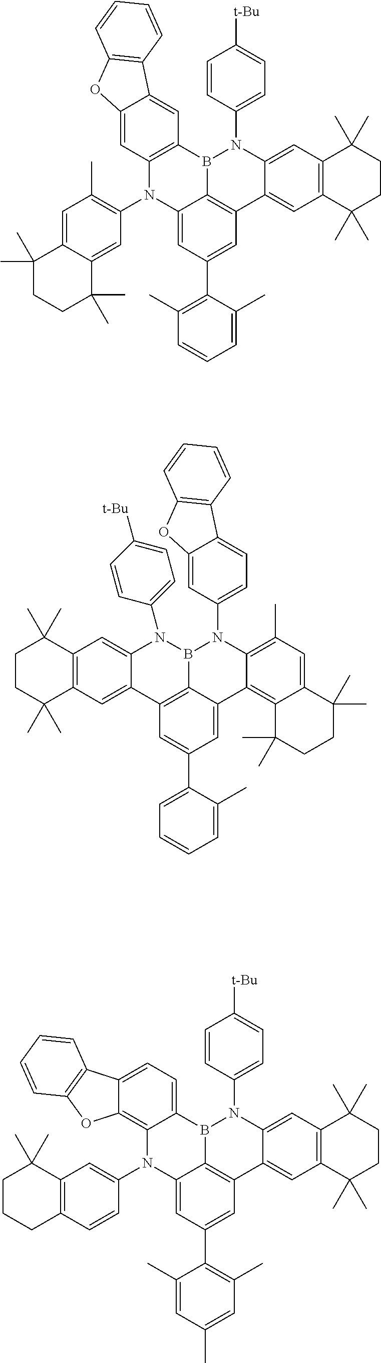 [SMILES: Cc1cc2c(cc1N1c3cc4oc5ccccc5c4cc3B3c4c(cc(-c5c(C)cccc5C)cc41)-c1cc4c(cc1N3c1ccc(C(C)(C)C)cc1)C(C)(C)CCC4(C)C)C(C)(C)CCC2(C)C ; Cc1ccccc1-c1cc2c3c(c1)-c1c(c(C)cc4c1C(C)(C)CCC4(C)C)N(c1ccc4c(c1)oc1ccccc14)B3N(c1ccc(C(C)(C)C)cc1)c1cc3c(cc1-2)C(C)(C)CCC3(C)C ; Cc1cc(C)c(-c2cc3c4c(c2)N(c2ccc5c(c2)C(C)(C)CCC5)c2c(ccc5c2oc2ccccc25)B4N(c2ccc(C(C)(C)C)cc2)c2cc4c(cc2-3)C(C)(C)CCC4(C)C)c(C)c1] 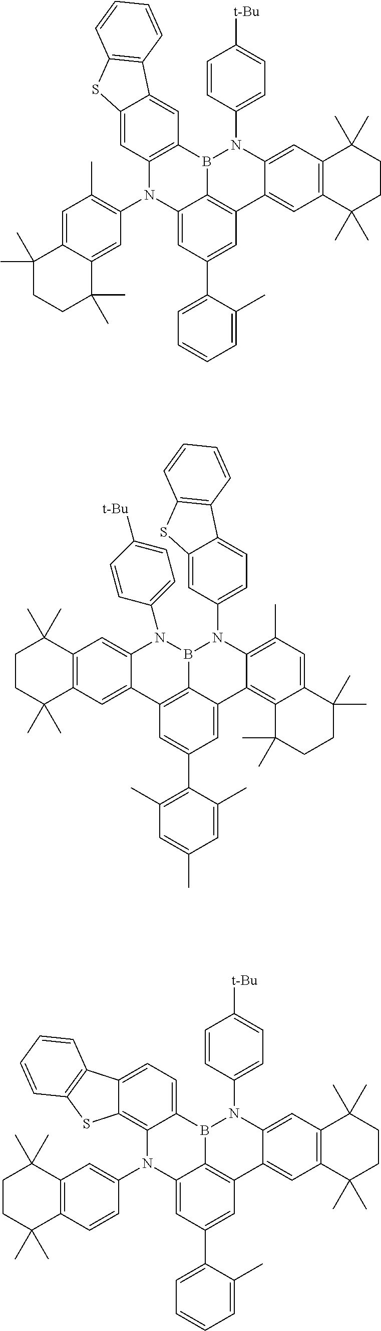 [SMILES: Cc1ccccc1-c1cc2c3c(c1)N(c1cc4c(cc1C)C(C)(C)CCC4(C)C)c1cc4sc5ccccc5c4cc1B3N(c1ccc(C(C)(C)C)cc1)c1cc3c(cc1-2)C(C)(C)CCC3(C)C ; Cc1cc(C)c(-c2cc3c4c(c2)-c2c(c(C)cc5c2C(C)(C)CCC5(C)C)N(c2ccc5c(c2)sc2ccccc25)B4N(c2ccc(C(C)(C)C)cc2)c2cc4c(cc2-3)C(C)(C)CCC4(C)C)c(C)c1 ; Cc1ccccc1-c1cc2c3c(c1)N(c1ccc4c(c1)C(C)(C)CCC4(C)C)c1c(ccc4c1sc1ccccc14)B3N(c1ccc(C(C)(C)C)cc1)c1cc3c(cc1-2)C(C)(C)CCC3(C)C] 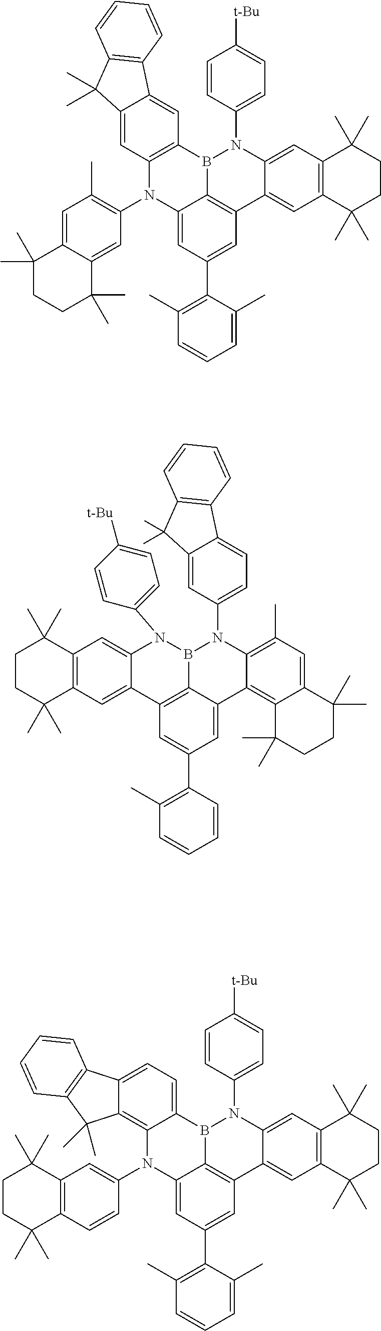 [SMILES: Cc1cc2c(cc1N1c3cc4c(cc3B3c5c(cc(-c6c(C)cccc6C)cc51)-c1cc5c(cc1N3c1ccc(C(C)(C)C)cc1)C(C)(C)CCC5(C)C)-c1ccccc1C4(C)C)C(C)(C)CCC2(C)C ; Cc1ccccc1-c1cc2c3c(c1)-c1c(c(C)cc4c1C(C)(C)CCC4(C)C)N(c1ccc4c(c1)C(C)(C)c1ccccc1-4)B3N(c1ccc(C(C)(C)C)cc1)c1cc3c(cc1-2)C(C)(C)CCC3(C)C ; Cc1cccc(C)c1-c1cc2c3c(c1)N(c1ccc4c(c1)C(C)(C)CCC4(C)C)c1c(ccc4c1C(C)(C)c1ccccc1-4)B3N(c1ccc(C(C)(C)C)cc1)c1cc3c(cc1-2)C(C)(C)CCC3(C)C] 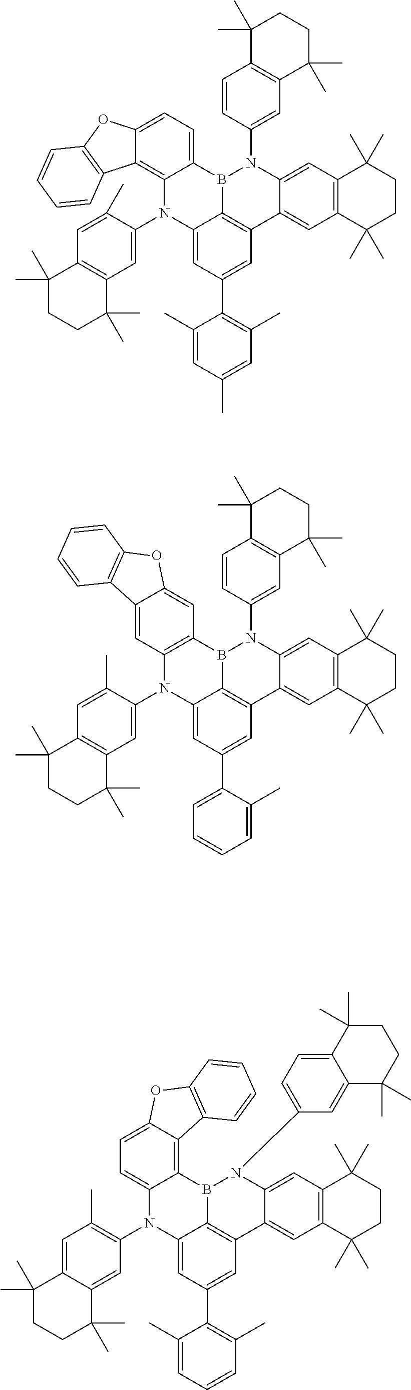 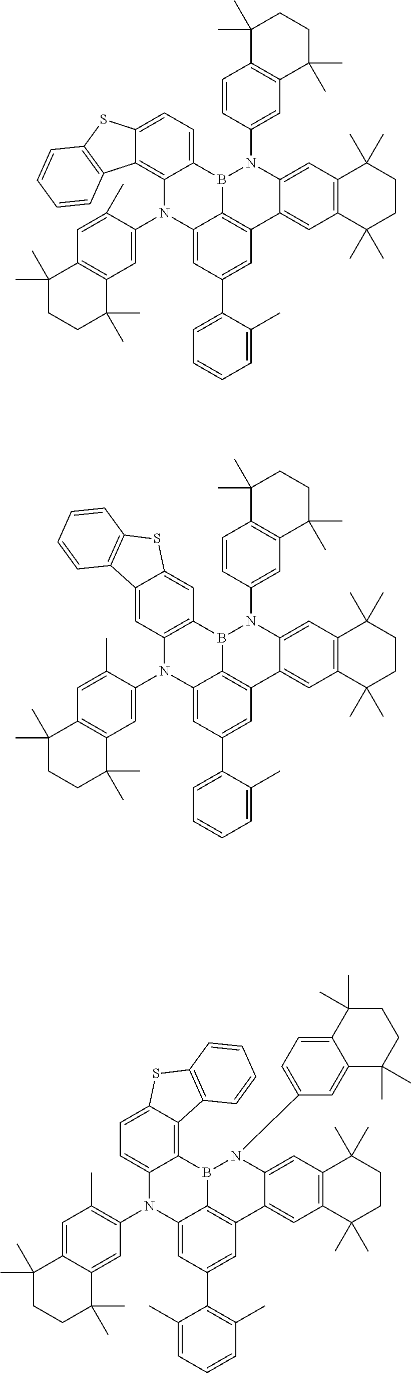 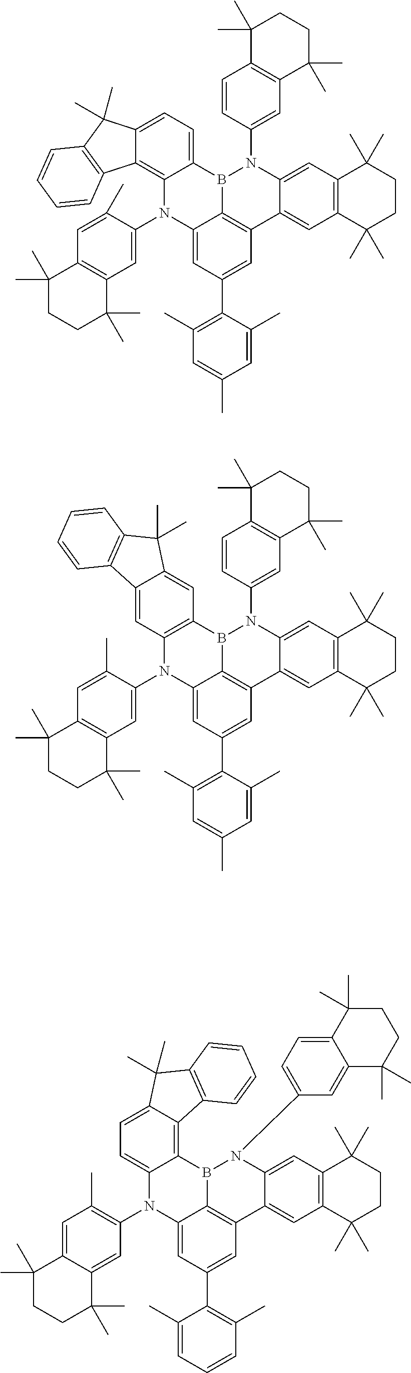 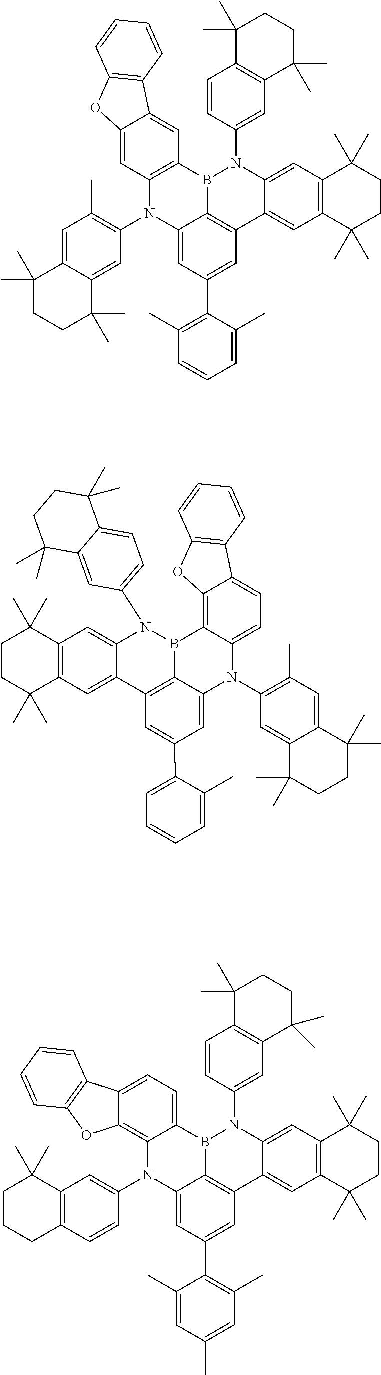 [SMILES: Cc1cc2c(cc1N1c3cc4oc5ccccc5c4cc3B3c4c(cc(-c5c(C)cccc5C)cc41)-c1cc4c(cc1N3c1ccc3c(c1)C(C)(C)CCC3(C)C)C(C)(C)CCC4(C)C)C(C)(C)CCC2(C)C ; Cc1ccccc1-c1cc2c3c(c1)N(c1cc4c(cc1C)C(C)(C)CCC4(C)C)c1ccc4c(oc5ccccc54)c1B3N(c1ccc3c(c1)C(C)(C)CCC3(C)C)c1cc3c(cc1-2)C(C)(C)CCC3(C)C ; Cc1cc(C)c(-c2cc3c4c(c2)N(c2ccc5c(c2)C(C)(C)CCC5)c2c(ccc5c2oc2ccccc25)B4N(c2ccc4c(c2)C(C)(C)CCC4(C)C)c2cc4c(cc2-3)C(C)(C)CCC4(C)C)c(C)c1] 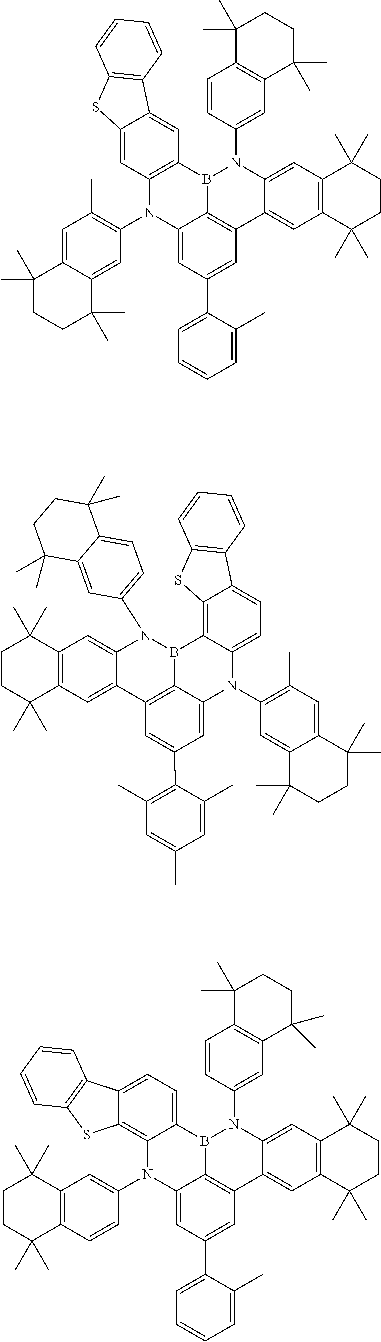 [SMILES: Cc1ccccc1-c1cc2c3c(c1)N(c1cc4c(cc1C)C(C)(C)CCC4(C)C)c1cc4sc5ccccc5c4cc1B3N(c1ccc3c(c1)C(C)(C)CCC3(C)C)c1cc3c(cc1-2)C(C)(C)CCC3(C)C ; Cc1cc(C)c(-c2cc3c4c(c2)N(c2cc5c(cc2C)C(C)(C)CCC5(C)C)c2ccc5c(sc6ccccc65)c2B4N(c2ccc4c(c2)C(C)(C)CCC4(C)C)c2cc4c(cc2-3)C(C)(C)CCC4(C)C)c(C)c1 ; Cc1ccccc1-c1cc2c3c(c1)N(c1ccc4c(c1)C(C)(C)CCC4(C)C)c1c(ccc4c1sc1ccccc14)B3N(c1ccc3c(c1)C(C)(C)CCC3(C)C)c1cc3c(cc1-2)C(C)(C)CCC3(C)C] 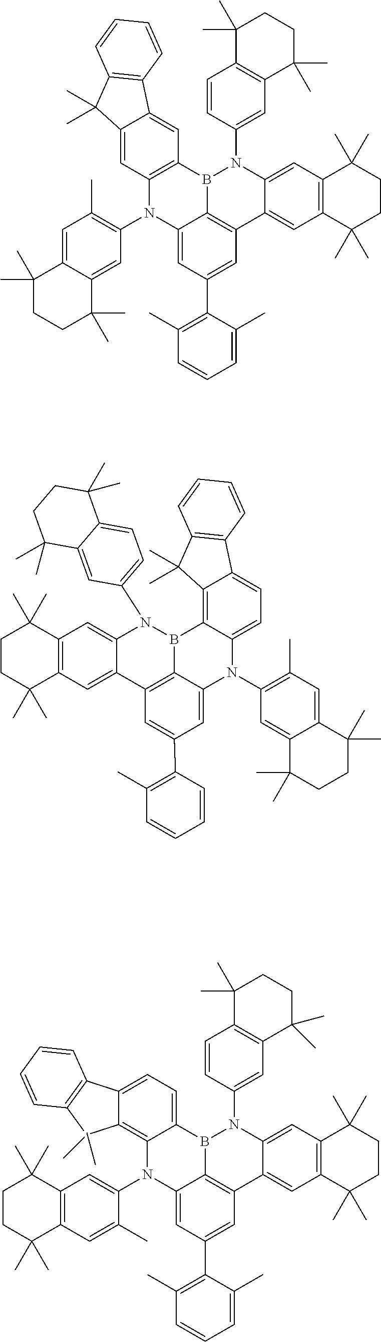 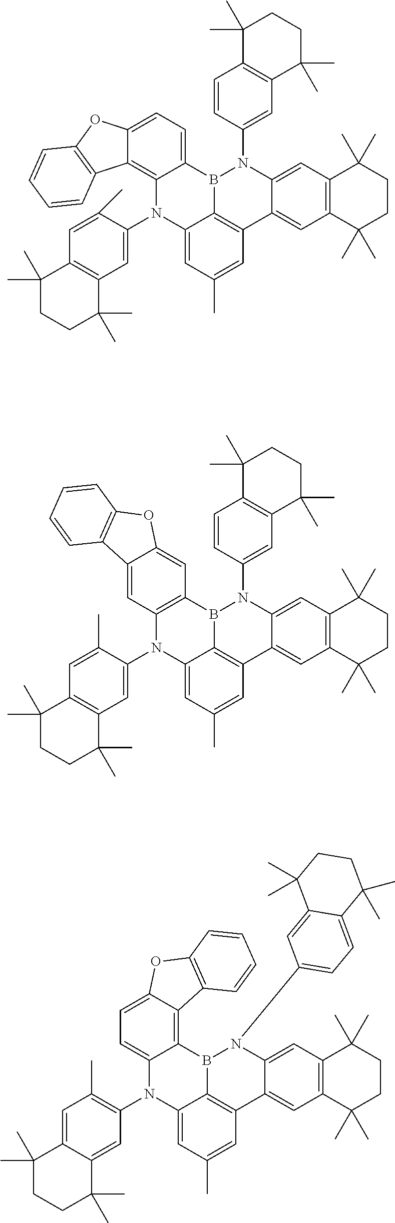 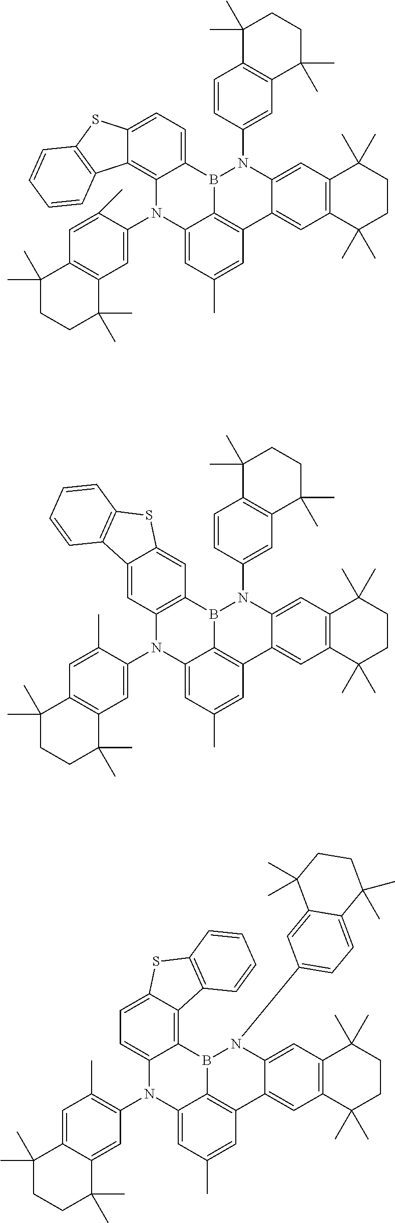 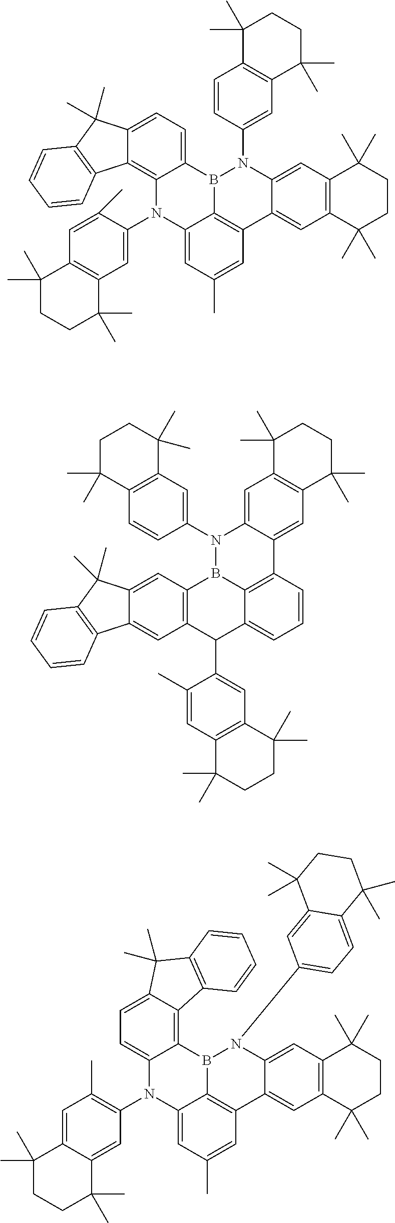 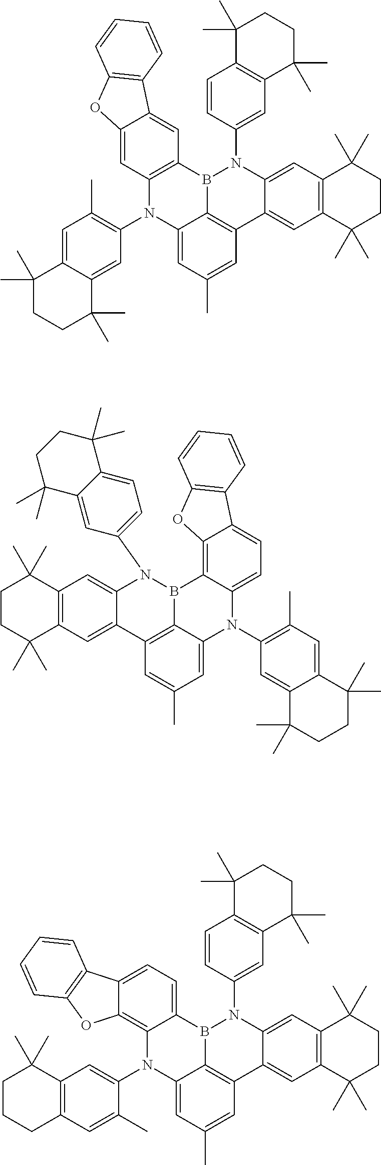 [SMILES: Cc1cc2c3c(c1)N(c1cc4c(cc1C)C(C)(C)CCC4(C)C)c1cc4oc5ccccc5c4cc1B3N(c1ccc3c(c1)C(C)(C)CCC3(C)C)c1cc3c(cc1-2)C(C)(C)CCC3(C)C ; Cc1cc2c3c(c1)N(c1cc4c(cc1C)C(C)(C)CCC4(C)C)c1ccc4c(oc5ccccc54)c1B3N(c1ccc3c(c1)C(C)(C)CCC3(C)C)c1cc3c(cc1-2)C(C)(C)CCC3(C)C ; Cc1cc2c3c(c1)N(c1cc4c(cc1C)CCCC4(C)C)c1c(ccc4c1oc1ccccc14)B3N(c1ccc3c(c1)C(C)(C)CCC3(C)C)c1cc3c(cc1-2)C(C)(C)CCC3(C)C] 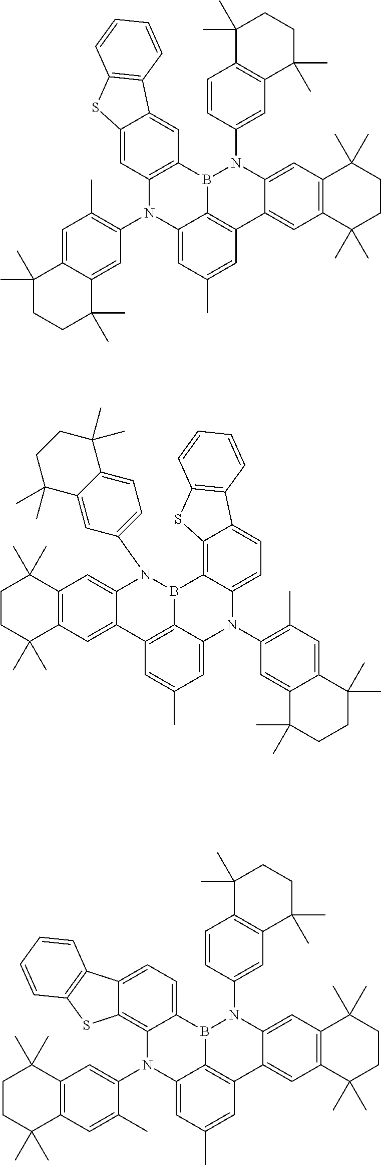 [SMILES: Cc1cc2c3c(c1)N(c1cc4c(cc1C)C(C)(C)CCC4(C)C)c1cc4sc5ccccc5c4cc1B3N(c1ccc3c(c1)C(C)(C)CCC3(C)C)c1cc3c(cc1-2)C(C)(C)CCC3(C)C ; Cc1cc2c3c(c1)N(c1cc4c(cc1C)C(C)(C)CCC4(C)C)c1ccc4c(sc5ccccc54)c1B3N(c1ccc3c(c1)C(C)(C)CCC3(C)C)c1cc3c(cc1-2)C(C)(C)CCC3(C)C ; Cc1cc2c3c(c1)N(c1cc4c(cc1C)C(C)(C)CCC4(C)C)c1c(ccc4c1sc1ccccc14)B3N(c1ccc3c(c1)C(C)(C)CCC3(C)C)c1cc3c(cc1-2)C(C)(C)CCC3(C)C] 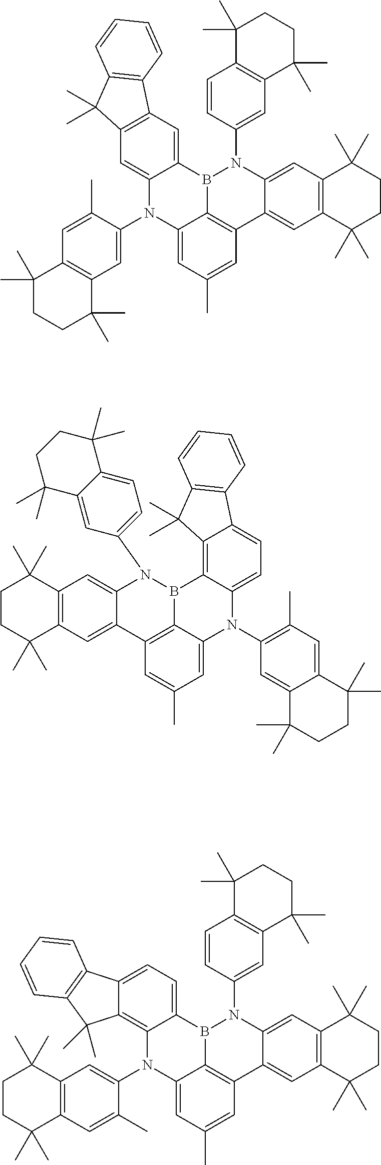 [SMILES: Cc1cc2c3c(c1)N(c1cc4c(cc1C)C(C)(C)CCC4(C)C)c1cc4c(cc1B3N(c1ccc3c(c1)C(C)(C)CCC3(C)C)c1cc3c(cc1-2)C(C)(C)CCC3(C)C)-c1ccccc1C4(C)C ; Cc1cc2c3c(c1)N(c1cc4c(cc1C)C(C)(C)CCC4(C)C)c1ccc4c(c1B3N(c1ccc3c(c1)C(C)(C)CCC3(C)C)c1cc3c(cc1-2)C(C)(C)CCC3(C)C)C(C)(C)c1ccccc1-4 ; Cc1cc2c3c(c1)N(c1cc4c(cc1C)C(C)(C)CCC4(C)C)c1c(ccc4c1C(C)(C)c1ccccc1-4)B3N(c1ccc3c(c1)C(C)(C)CCC3(C)C)c1cc3c(cc1-2)C(C)(C)CCC3(C)C] 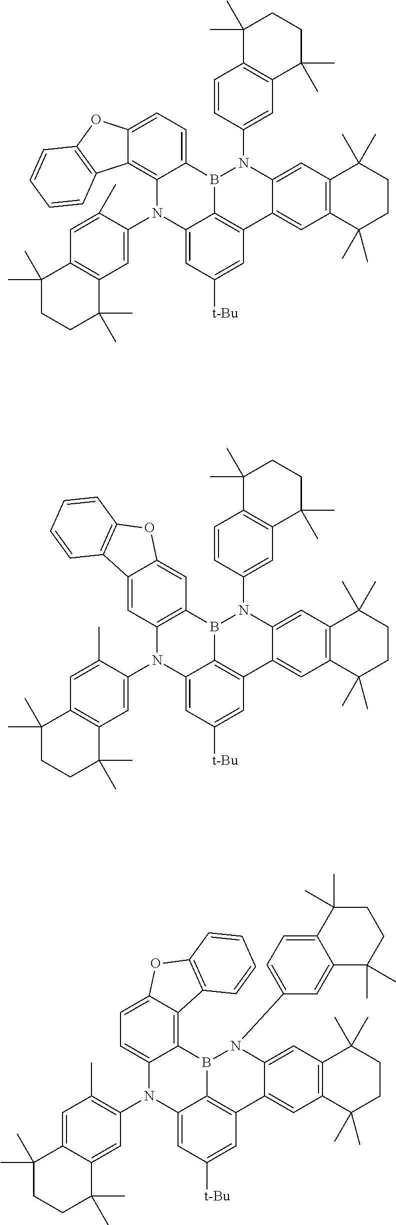 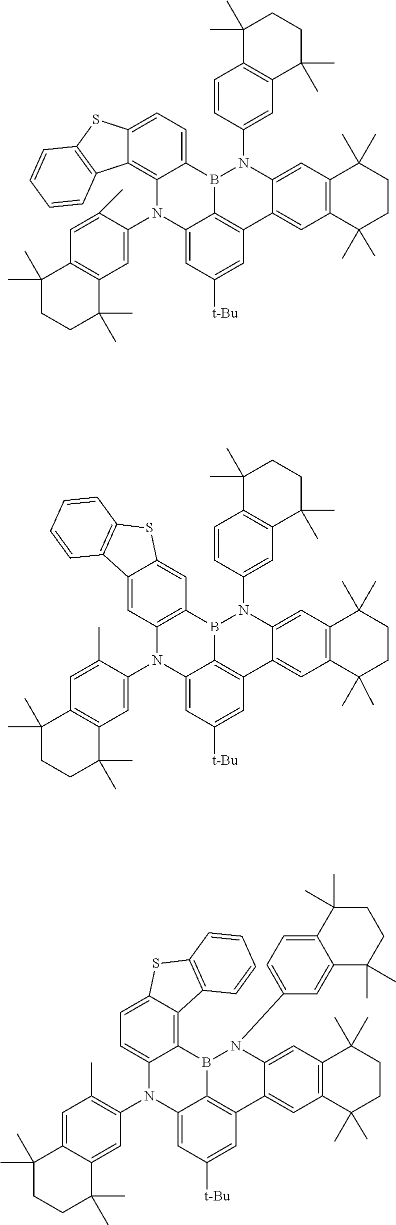 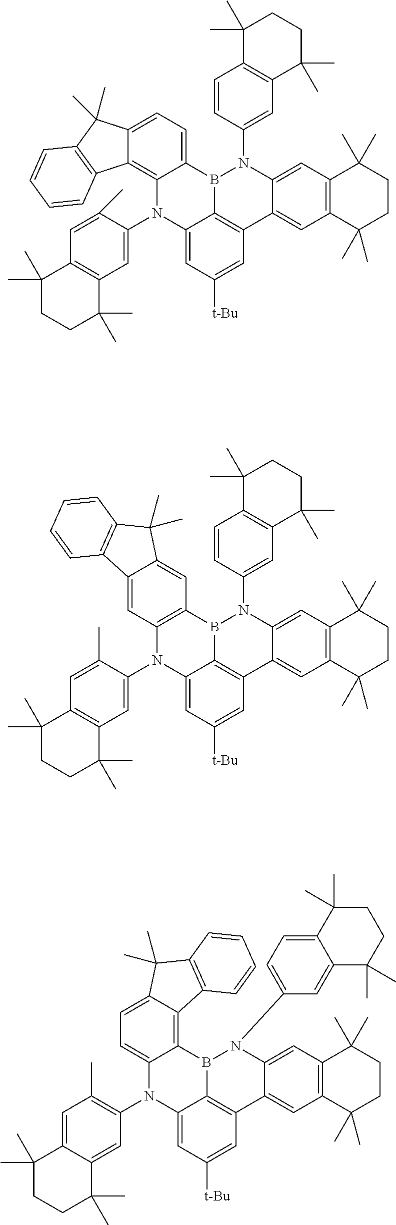 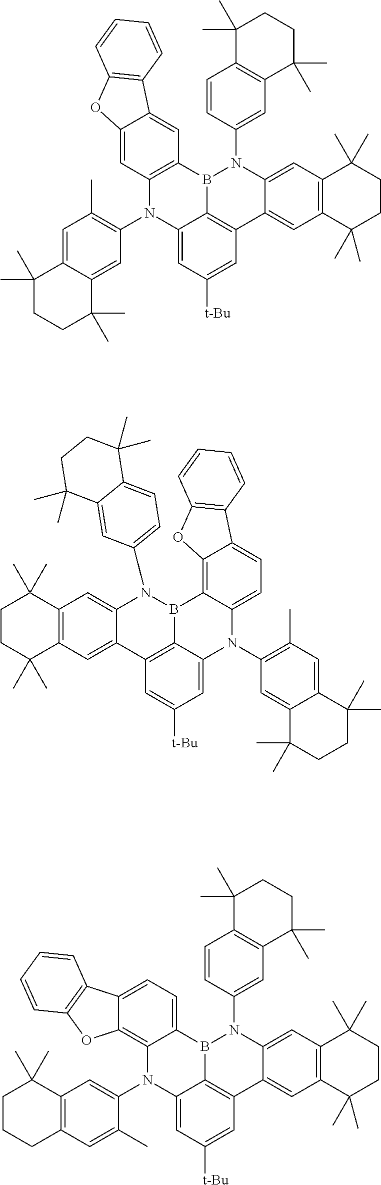 [SMILES: Cc1cc2c(cc1N1c3cc4oc5ccccc5c4cc3B3c4c(cc(C(C)(C)C)cc41)-c1cc4c(cc1N3c1ccc3c(c1)C(C)(C)CCC3(C)C)C(C)(C)CCC4(C)C)C(C)(C)CCC2(C)C ; Cc1cc2c(cc1N1c3cc(C(C)(C)C)cc4c3B(c3c1ccc1c3oc3ccccc31)N(c1ccc3c(c1)C(C)(C)CCC3(C)C)c1cc3c(cc1-4)C(C)(C)CCC3(C)C)C(C)(C)CCC2(C)C ; Cc1cc2c(cc1N1c3cc(C(C)(C)C)cc4c3B(c3ccc5c(oc6ccccc65)c31)N(c1ccc3c(c1)C(C)(C)CCC3(C)C)c1cc3c(cc1-4)C(C)(C)CCC3(C)C)C(C)(C)CCC2] 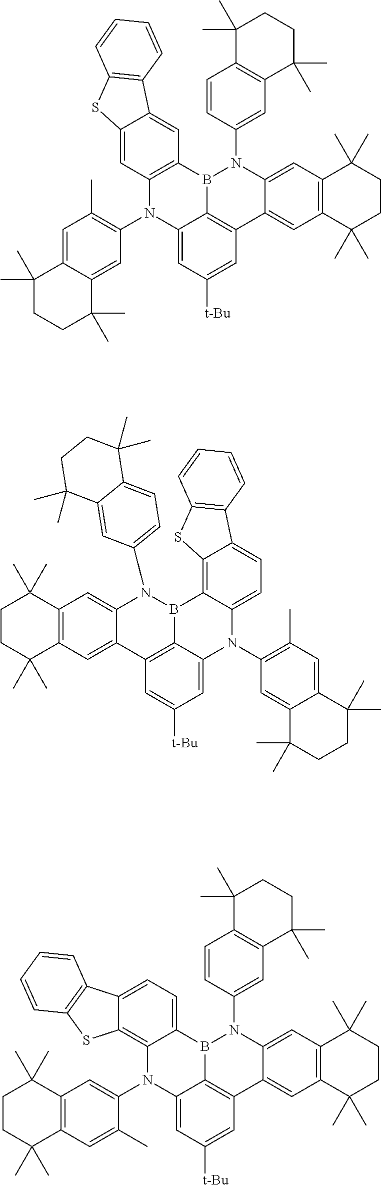 [SMILES: Cc1cc2c(cc1N1c3cc4sc5ccccc5c4cc3B3c4c(cc(C(C)(C)C)cc41)-c1cc4c(cc1N3c1ccc3c(c1)C(C)(C)CCC3(C)C)C(C)(C)CCC4(C)C)C(C)(C)CCC2(C)C ; Cc1cc2c(cc1N1c3cc(C(C)(C)C)cc4c3B(c3c1ccc1c3sc3ccccc31)N(c1ccc3c(c1)C(C)(C)CCC3(C)C)c1cc3c(cc1-4)C(C)(C)CCC3(C)C)C(C)(C)CCC2(C)C ; Cc1cc2c(cc1N1c3cc(C(C)(C)C)cc4c3B(c3ccc5c(sc6ccccc65)c31)N(c1ccc3c(c1)C(C)(C)CCC3(C)C)c1cc3c(cc1-4)C(C)(C)CCC3(C)C)C(C)(C)CCC2(C)C] 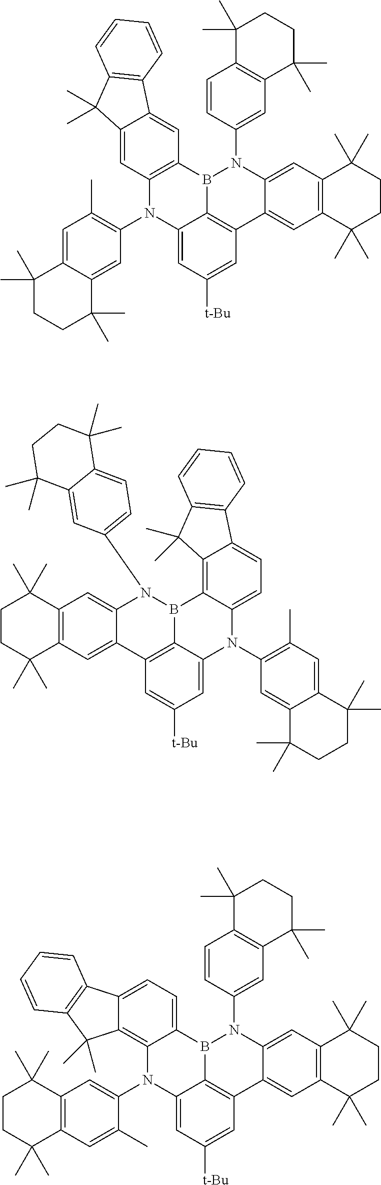 [SMILES: Cc1cc2c(cc1N1c3cc4c(cc3B3c5c(cc(C(C)(C)C)cc51)-c1cc5c(cc1N3c1ccc3c(c1)C(C)(C)CCC3(C)C)C(C)(C)CCC5(C)C)-c1ccccc1C4(C)C)C(C)(C)CCC2(C)C ; Cc1cc2c(cc1N1c3cc(C(C)(C)C)cc4c3B(c3c1ccc1c3C(C)(C)c3ccccc3-1)N(c1ccc3c(c1)C(C)(C)CCC3(C)C)c1cc3c(cc1-4)C(C)(C)CCC3(C)C)C(C)(C)CCC2(C)C ; Cc1cc2c(cc1N1c3cc(C(C)(C)C)cc4c3B(c3ccc5c(c31)C(C)(C)c1ccccc1-5)N(c1ccc3c(c1)C(C)(C)CCC3(C)C)c1cc3c(cc1-4)C(C)(C)CCC3(C)C)C(C)(C)CCC2(C)C] 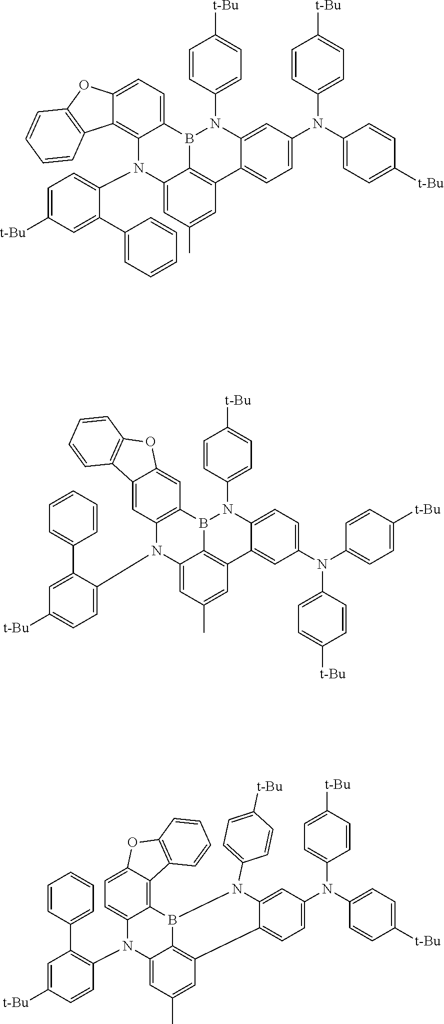 [SMILES: Cc1cc2c3c(c1)N(c1ccc(C(C)(C)C)cc1-c1ccccc1)c1c(ccc4oc5ccccc5c14)B3N(c1ccc(C(C)(C)C)cc1)c1cc(N(c3ccc(C(C)(C)C)cc3)c3ccc(C(C)(C)C)cc3)ccc1-2 ; Cc1cc2c3c(c1)N(c1ccc(C(C)(C)C)cc1-c1ccccc1)c1cc4c(cc1B3N(c1ccc(C(C)(C)C)cc1)c1ccc(N(c3ccc(C(C)(C)C)cc3)c3ccc(C(C)(C)C)cc3)cc1-2)oc1ccccc14 ; Cc1cc2c3c(c1)N(c1ccc(C(C)(C)C)cc1-c1ccccc1)c1ccc4oc5ccccc5c4c1B3N(c1ccc(C(C)(C)C)cc1)c1cc(N(c3ccc(C(C)(C)C)cc3)c3ccc(C(C)(C)C)cc3)ccc1-2] 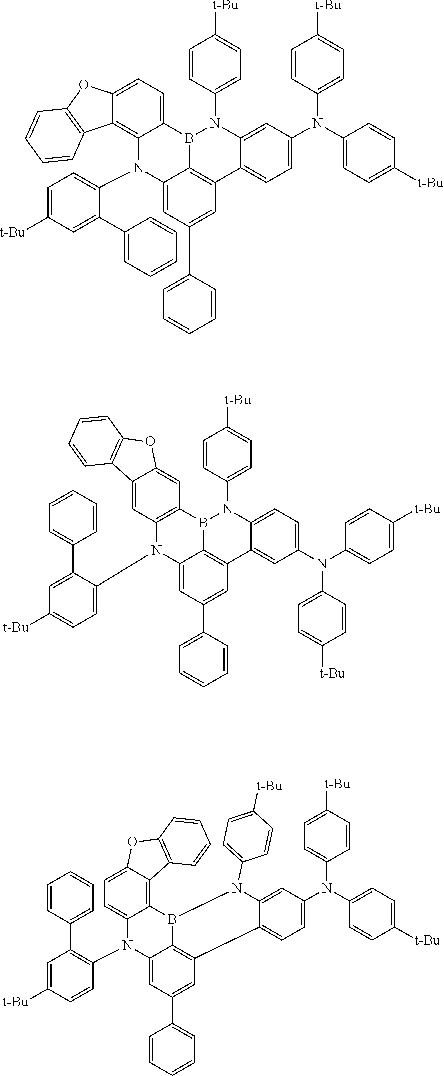 [SMILES: CC(C)(C)c1ccc(N2B3c4ccc5oc6ccccc6c5c4N(c4ccc(C(C)(C)C)cc4-c4ccccc4)c4cc(-c5ccccc5)cc(c43)-c3ccc(N(c4ccc(C(C)(C)C)cc4)c4ccc(C(C)(C)C)cc4)cc32)cc1 ; CC(C)(C)c1ccc(N2B3c4cc5oc6ccccc6c5cc4N(c4ccc(C(C)(C)C)cc4-c4ccccc4)c4cc(-c5ccccc5)cc(c43)-c3cc(N(c4ccc(C(C)(C)C)cc4)c4ccc(C(C)(C)C)cc4)ccc32)cc1 ; CC(C)(C)c1ccc(N2B3c4c(cc(-c5ccccc5)cc4N(c4ccc(C(C)(C)C)cc4-c4ccccc4)c4ccc5oc6ccccc6c5c43)-c3ccc(N(c4ccc(C(C)(C)C)cc4)c4ccc(C(C)(C)C)cc4)cc32)cc1] 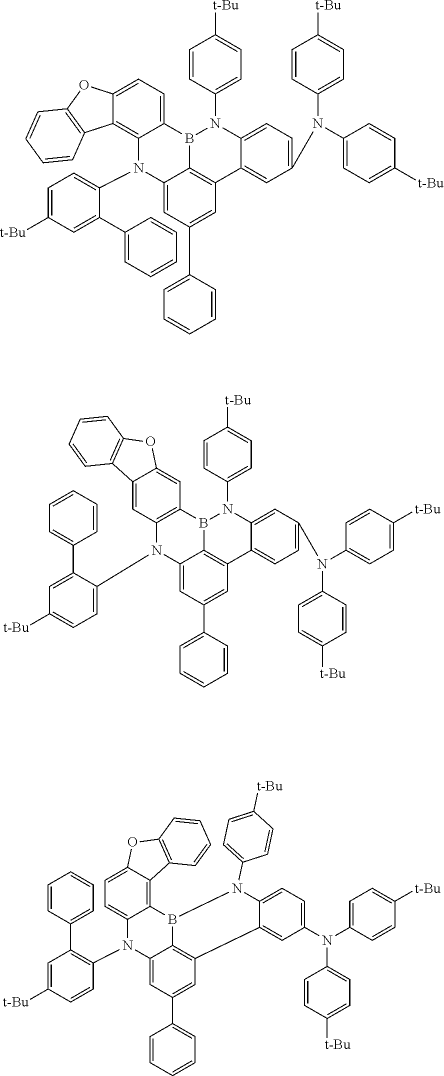 [SMILES: CC(C)(C)c1ccc(N2B3c4ccc5oc6ccccc6c5c4N(c4ccc(C(C)(C)C)cc4-c4ccccc4)c4cc(-c5ccccc5)cc(c43)-c3cc(N(c4ccc(C(C)(C)C)cc4)c4ccc(C(C)(C)C)cc4)ccc32)cc1 ; CC(C)(C)c1ccc(N2B3c4cc5oc6ccccc6c5cc4N(c4ccc(C(C)(C)C)cc4-c4ccccc4)c4cc(-c5ccccc5)cc(c43)-c3ccc(N(c4ccc(C(C)(C)C)cc4)c4ccc(C(C)(C)C)cc4)cc32)cc1 ; CC(C)(C)c1ccc(N2B3c4c(cc(-c5ccccc5)cc4N(c4ccc(C(C)(C)C)cc4-c4ccccc4)c4ccc5oc6ccccc6c5c43)-c3cc(N(c4ccc(C(C)(C)C)cc4)c4ccc(C(C)(C)C)cc4)ccc32)cc1] 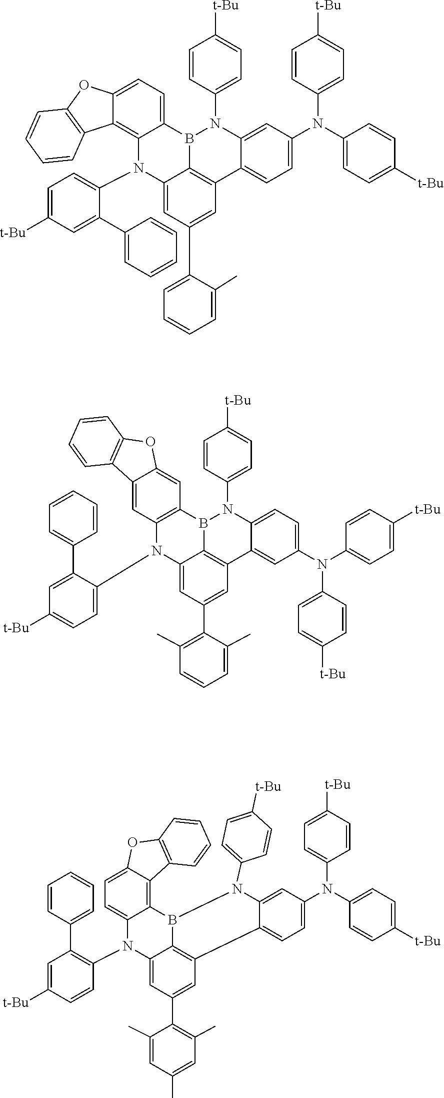 [SMILES: Cc1ccccc1-c1cc2c3c(c1)N(c1ccc(C(C)(C)C)cc1-c1ccccc1)c1c(ccc4oc5ccccc5c14)B3N(c1ccc(C(C)(C)C)cc1)c1cc(N(c3ccc(C(C)(C)C)cc3)c3ccc(C(C)(C)C)cc3)ccc1-2 ; Cc1cccc(C)c1-c1cc2c3c(c1)N(c1ccc(C(C)(C)C)cc1-c1ccccc1)c1cc4c(cc1B3N(c1ccc(C(C)(C)C)cc1)c1ccc(N(c3ccc(C(C)(C)C)cc3)c3ccc(C(C)(C)C)cc3)cc1-2)oc1ccccc14 ; Cc1cc(C)c(-c2cc3c4c(c2)N(c2ccc(C(C)(C)C)cc2-c2ccccc2)c2ccc5oc6ccccc6c5c2B4N(c2ccc(C(C)(C)C)cc2)c2cc(N(c4ccc(C(C)(C)C)cc4)c4ccc(C(C)(C)C)cc4)ccc2-3)c(C)c1] 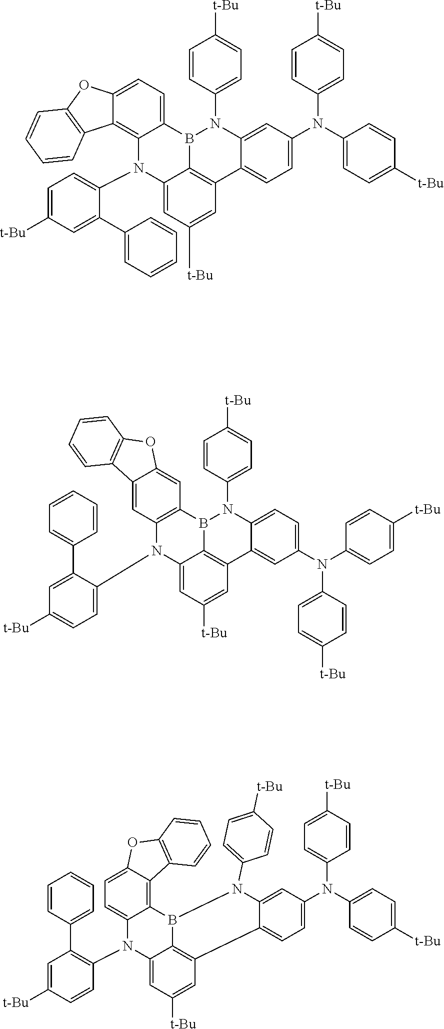 [SMILES: CC(C)(C)c1ccc(N2B3c4ccc5oc6ccccc6c5c4N(c4ccc(C(C)(C)C)cc4-c4ccccc4)c4cc(C(C)(C)C)cc(c43)-c3ccc(N(c4ccc(C(C)(C)C)cc4)c4ccc(C(C)(C)C)cc4)cc32)cc1 ; CC(C)(C)c1ccc(N2B3c4cc5oc6ccccc6c5cc4N(c4ccc(C(C)(C)C)cc4-c4ccccc4)c4cc(C(C)(C)C)cc(c43)-c3cc(N(c4ccc(C(C)(C)C)cc4)c4ccc(C(C)(C)C)cc4)ccc32)cc1 ; CC(C)(C)c1ccc(N2B3c4c(cc(C(C)(C)C)cc4N(c4ccc(C(C)(C)C)cc4-c4ccccc4)c4ccc5oc6ccccc6c5c43)-c3ccc(N(c4ccc(C(C)(C)C)cc4)c4ccc(C(C)(C)C)cc4)cc32)cc1] 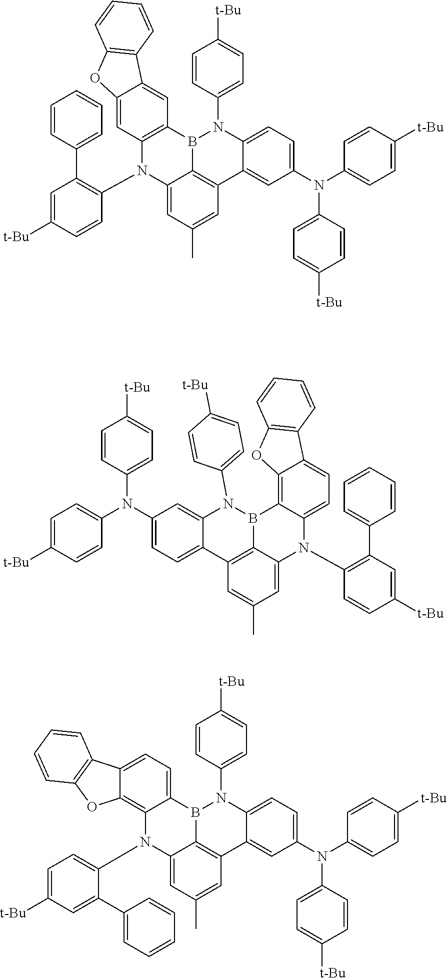 [SMILES: Cc1cc2c3c(c1)N(c1ccc(C(C)(C)C)cc1-c1ccccc1)c1cc4oc5ccccc5c4cc1B3N(c1ccc(C(C)(C)C)cc1)c1ccc(N(c3ccc(C(C)(C)C)cc3)c3ccc(C(C)(C)C)cc3)cc1-2 ; Cc1cc2c3c(c1)N(c1ccc(C(C)(C)C)cc1-c1ccccc1)c1ccc4c(oc5ccccc54)c1B3N(c1ccc(C(C)(C)C)cc1)c1cc(N(c3ccc(C(C)(C)C)cc3)c3ccc(C(C)(C)C)cc3)ccc1-2 ; Cc1cc2c3c(c1)N(c1ccc(C(C)(C)C)cc1-c1ccccc1)c1c(ccc4c1oc1ccccc14)B3N(c1ccc(C(C)(C)C)cc1)c1ccc(N(c3ccc(C(C)(C)C)cc3)c3ccc(C(C)(C)C)cc3)cc1-2] 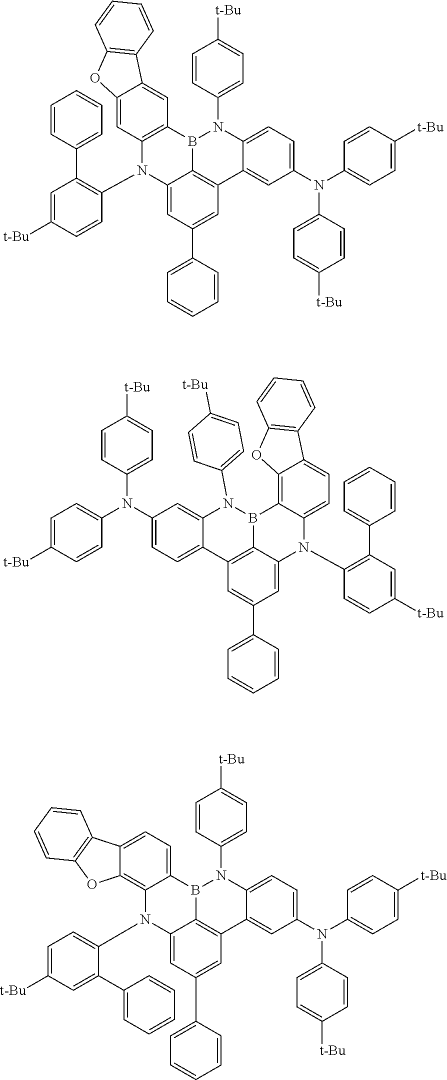 [SMILES: CC(C)(C)c1ccc(N2B3c4cc5c(cc4N(c4ccc(C(C)(C)C)cc4-c4ccccc4)c4cc(-c6ccccc6)cc(c43)-c3cc(N(c4ccc(C(C)(C)C)cc4)c4ccc(C(C)(C)C)cc4)ccc32)oc2ccccc25)cc1 ; CC(C)(C)c1ccc(N2B3c4c(cc(-c5ccccc5)cc4N(c4ccc(C(C)(C)C)cc4-c4ccccc4)c4ccc5c(oc6ccccc65)c43)-c3ccc(N(c4ccc(C(C)(C)C)cc4)c4ccc(C(C)(C)C)cc4)cc32)cc1 ; CC(C)(C)c1ccc(N2B3c4ccc5c(oc6ccccc65)c4N(c4ccc(C(C)(C)C)cc4-c4ccccc4)c4cc(-c5ccccc5)cc(c43)-c3cc(N(c4ccc(C(C)(C)C)cc4)c4ccc(C(C)(C)C)cc4)ccc32)cc1] 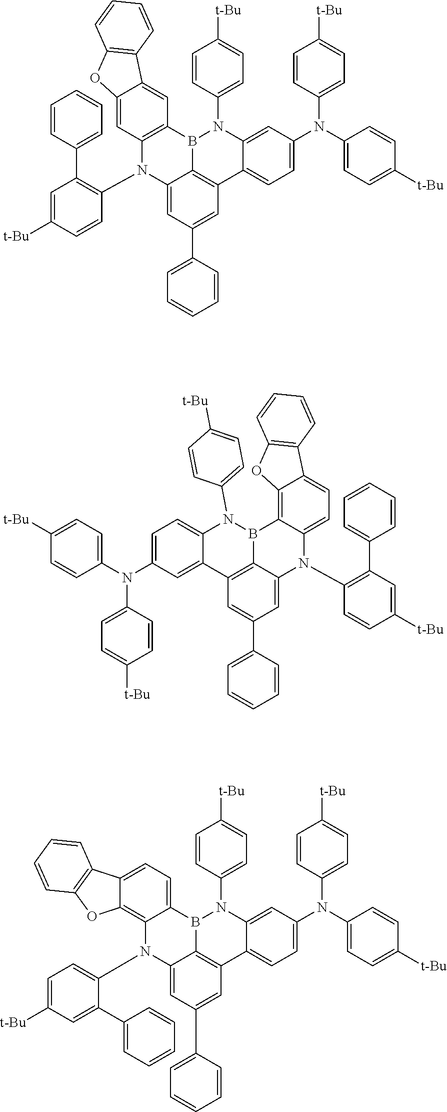 [SMILES: CC(C)(C)c1ccc(N2B3c4cc5c(cc4N(c4ccc(C(C)(C)C)cc4-c4ccccc4)c4cc(-c6ccccc6)cc(c43)-c3ccc(N(c4ccc(C(C)(C)C)cc4)c4ccc(C(C)(C)C)cc4)cc32)oc2ccccc25)cc1 ; CC(C)(C)c1ccc(N2B3c4c(cc(-c5ccccc5)cc4N(c4ccc(C(C)(C)C)cc4-c4ccccc4)c4ccc5c(oc6ccccc65)c43)-c3cc(N(c4ccc(C(C)(C)C)cc4)c4ccc(C(C)(C)C)cc4)ccc32)cc1 ; CC(C)(C)c1ccc(N2B3c4ccc5c(oc6ccccc65)c4N(c4ccc(C(C)(C)C)cc4-c4ccccc4)c4cc(-c5ccccc5)cc(c43)-c3ccc(N(c4ccc(C(C)(C)C)cc4)c4ccc(C(C)(C)C)cc4)cc32)cc1] 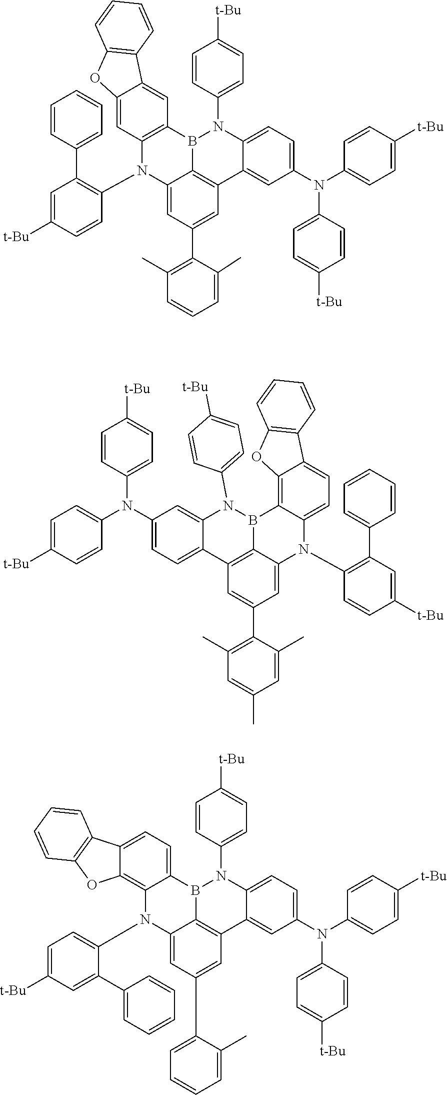 [SMILES: Cc1cccc(C)c1-c1cc2c3c(c1)N(c1ccc(C(C)(C)C)cc1-c1ccccc1)c1cc4oc5ccccc5c4cc1B3N(c1ccc(C(C)(C)C)cc1)c1ccc(N(c3ccc(C(C)(C)C)cc3)c3ccc(C(C)(C)C)cc3)cc1-2 ; Cc1cc(C)c(-c2cc3c4c(c2)N(c2ccc(C(C)(C)C)cc2-c2ccccc2)c2ccc5c(oc6ccccc65)c2B4N(c2ccc(C(C)(C)C)cc2)c2cc(N(c4ccc(C(C)(C)C)cc4)c4ccc(C(C)(C)C)cc4)ccc2-3)c(C)c1 ; Cc1ccccc1-c1cc2c3c(c1)N(c1ccc(C(C)(C)C)cc1-c1ccccc1)c1c(ccc4c1oc1ccccc14)B3N(c1ccc(C(C)(C)C)cc1)c1ccc(N(c3ccc(C(C)(C)C)cc3)c3ccc(C(C)(C)C)cc3)cc1-2] 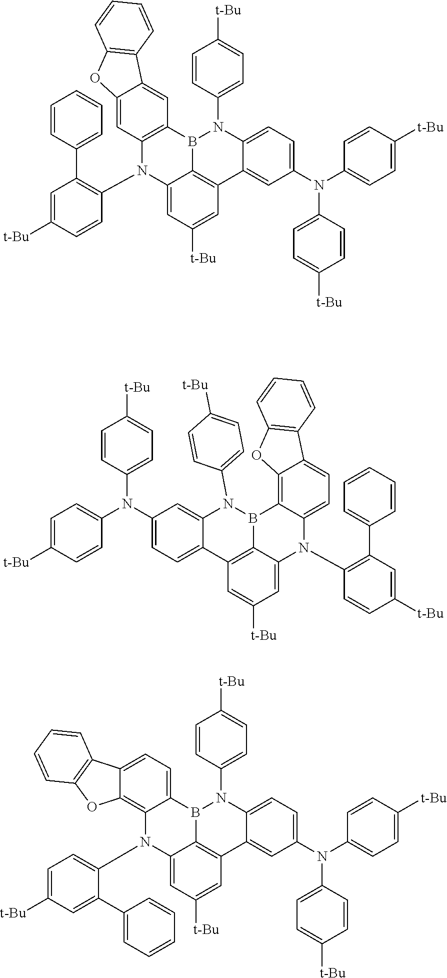 [SMILES: CC(C)(C)c1ccc(N2B3c4cc5c(cc4N(c4ccc(C(C)(C)C)cc4-c4ccccc4)c4cc(C(C)(C)C)cc(c43)-c3cc(N(c4ccc(C(C)(C)C)cc4)c4ccc(C(C)(C)C)cc4)ccc32)oc2ccccc25)cc1 ; CC(C)(C)c1ccc(N2B3c4c(cc(C(C)(C)C)cc4N(c4ccc(C(C)(C)C)cc4-c4ccccc4)c4ccc5c(oc6ccccc65)c43)-c3ccc(N(c4ccc(C(C)(C)C)cc4)c4ccc(C(C)(C)C)cc4)cc32)cc1 ; CC(C)(C)c1ccc(N2B3c4ccc5c(oc6ccccc65)c4N(c4ccc(C(C)(C)C)cc4-c4ccccc4)c4cc(C(C)(C)C)cc(c43)-c3cc(N(c4ccc(C(C)(C)C)cc4)c4ccc(C(C)(C)C)cc4)ccc32)cc1] 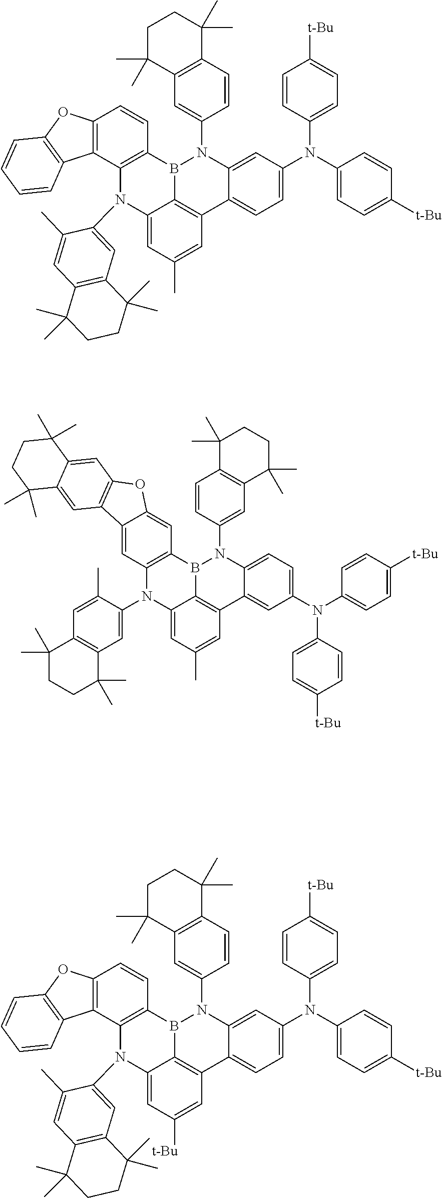 [SMILES: Cc1cc2c3c(c1)N(c1cc4c(cc1C)C(C)(C)CCC4(C)C)c1c(ccc4oc5ccccc5c14)B3N(c1ccc3c(c1)C(C)(C)CCC3(C)C)c1cc(N(c3ccc(C(C)(C)C)cc3)c3ccc(C(C)(C)C)cc3)ccc1-2 ; Cc1cc2c3c(c1)N(c1cc4c(cc1C)C(C)(C)CCC4(C)C)c1cc4c(cc1B3N(c1ccc3c(c1)C(C)(C)CCC3(C)C)c1ccc(N(c3ccc(C(C)(C)C)cc3)c3ccc(C(C)(C)C)cc3)cc1-2)oc1cc2c(cc14)C(C)(C)CCC2(C)C ; Cc1cc2c(cc1N1c3cc(C(C)(C)C)cc4c3B(c3ccc5oc6ccccc6c5c31)N(c1ccc3c(c1)C(C)(C)CCC3(C)C)c1cc(N(c3ccc(C(C)(C)C)cc3)c3ccc(C(C)(C)C)cc3)ccc1-4)C(C)(C)CCC2(C)C] 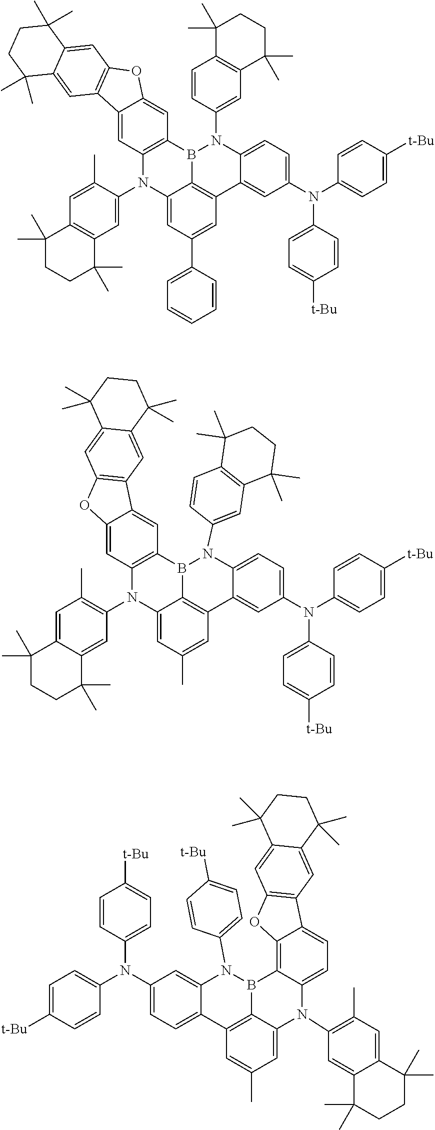 [SMILES: Cc1cc2c(cc1N1c3cc4c(cc3B3c5c(cc(-c6ccccc6)cc51)-c1cc(N(c5ccc(C(C)(C)C)cc5)c5ccc(C(C)(C)C)cc5)ccc1N3c1ccc3c(c1)C(C)(C)CCC3(C)C)oc1cc3c(cc14)C(C)(C)CCC3(C)C)C(C)(C)CCC2(C)C ; Cc1cc2c3c(c1)N(c1cc4c(cc1C)C(C)(C)CCC4(C)C)c1cc4oc5cc6c(cc5c4cc1B3N(c1ccc3c(c1)C(C)(C)CCC3(C)C)c1ccc(N(c3ccc(C(C)(C)C)cc3)c3ccc(C(C)(C)C)cc3)cc1-2)C(C)(C)CCC6(C)C ; Cc1cc2c3c(c1)N(c1cc4c(cc1C)C(C)(C)CCC4(C)C)c1ccc4c(oc5cc6c(cc54)C(C)(C)CCC6(C)C)c1B3N(c1ccc(C(C)(C)C)cc1)c1cc(N(c3ccc(C(C)(C)C)cc3)c3ccc(C(C)(C)C)cc3)ccc1-2] 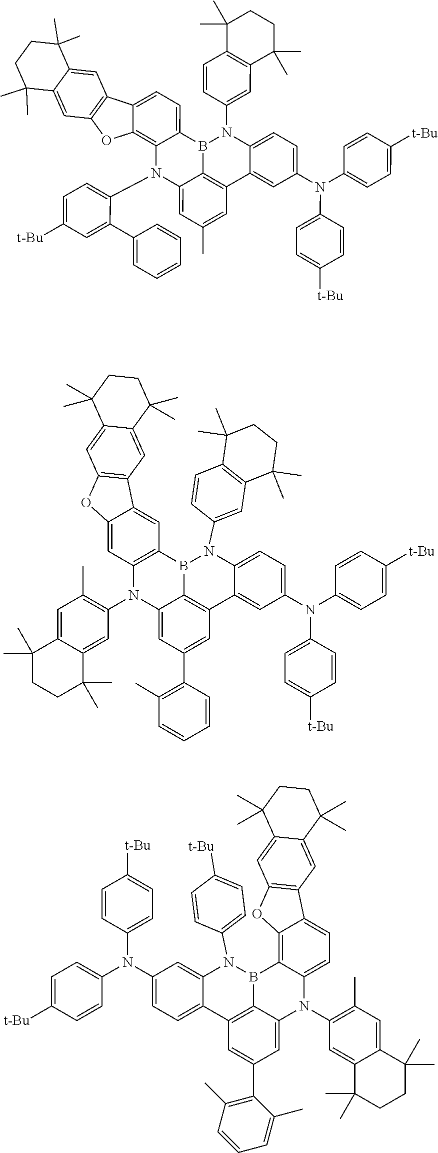 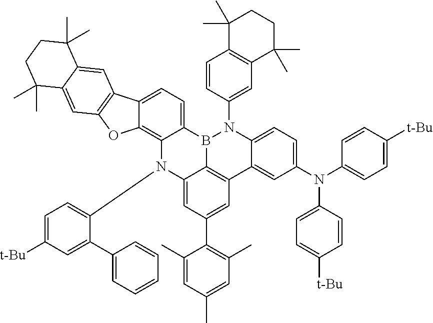 [SMILES: Cc1cc(C)c(-c2cc3c4c(c2)N(c2ccc(C(C)(C)C)cc2-c2ccccc2)c2c(ccc5c2oc2cc6c(cc25)C(C)(C)CCC6(C)C)B4N(c2ccc4c(c2)C(C)(C)CCC4(C)C)c2ccc(N(c4ccc(C(C)(C)C)cc4)c4ccc(C(C)(C)C)cc4)cc2-3)c(C)c1] 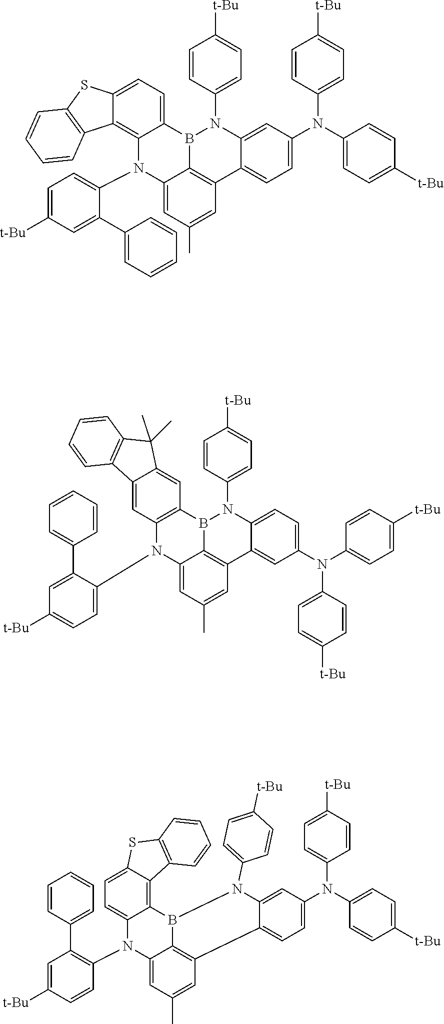 [SMILES: Cc1cc2c3c(c1)N(c1ccc(C(C)(C)C)cc1-c1ccccc1)c1c(ccc4sc5ccccc5c14)B3N(c1ccc(C(C)(C)C)cc1)c1cc(N(c3ccc(C(C)(C)C)cc3)c3ccc(C(C)(C)C)cc3)ccc1-2 ; Cc1cc2c3c(c1)N(c1ccc(C(C)(C)C)cc1-c1ccccc1)c1cc4c(cc1B3N(c1ccc(C(C)(C)C)cc1)c1ccc(N(c3ccc(C(C)(C)C)cc3)c3ccc(C(C)(C)C)cc3)cc1-2)C(C)(C)c1ccccc1-4 ; Cc1cc2c3c(c1)N(c1ccc(C(C)(C)C)cc1-c1ccccc1)c1ccc4sc5ccccc5c4c1B3N(c1ccc(C(C)(C)C)cc1)c1cc(N(c3ccc(C(C)(C)C)cc3)c3ccc(C(C)(C)C)cc3)ccc1-2] 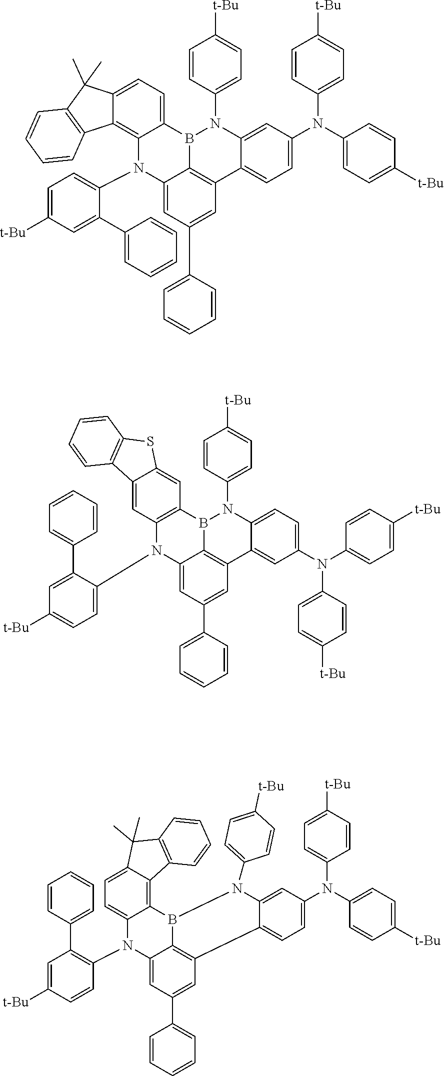 [SMILES: CC(C)(C)c1ccc(N2B3c4ccc5c(c4N(c4ccc(C(C)(C)C)cc4-c4ccccc4)c4cc(-c6ccccc6)cc(c43)-c3ccc(N(c4ccc(C(C)(C)C)cc4)c4ccc(C(C)(C)C)cc4)cc32)-c2ccccc2C5(C)C)cc1 ; CC(C)(C)c1ccc(N2B3c4cc5sc6ccccc6c5cc4N(c4ccc(C(C)(C)C)cc4-c4ccccc4)c4cc(-c5ccccc5)cc(c43)-c3cc(N(c4ccc(C(C)(C)C)cc4)c4ccc(C(C)(C)C)cc4)ccc32)cc1 ; CC(C)(C)c1ccc(N2B3c4c(cc(-c5ccccc5)cc4N(c4ccc(C(C)(C)C)cc4-c4ccccc4)c4ccc5c(c43)-c3ccccc3C5(C)C)-c3ccc(N(c4ccc(C(C)(C)C)cc4)c4ccc(C(C)(C)C)cc4)cc32)cc1] 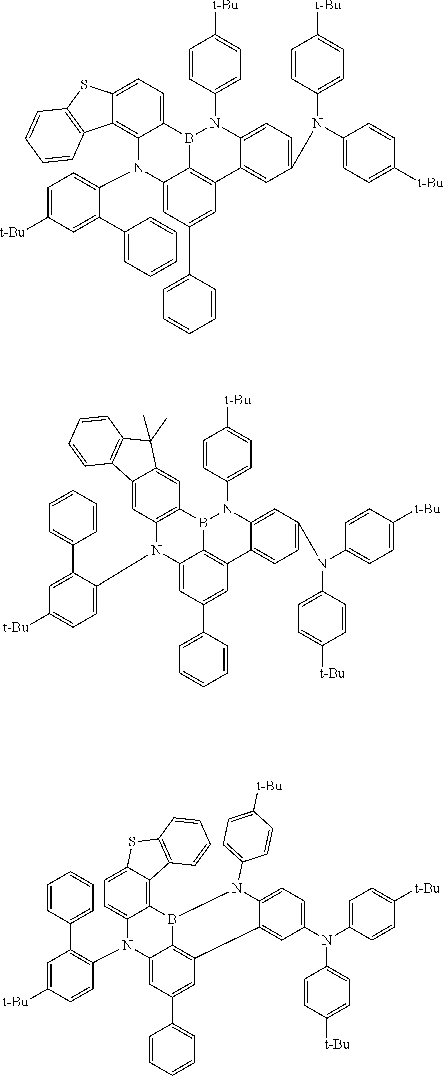 [SMILES: CC(C)(C)c1ccc(N2B3c4ccc5sc6ccccc6c5c4N(c4ccc(C(C)(C)C)cc4-c4ccccc4)c4cc(-c5ccccc5)cc(c43)-c3cc(N(c4ccc(C(C)(C)C)cc4)c4ccc(C(C)(C)C)cc4)ccc32)cc1 ; CC(C)(C)c1ccc(N2B3c4cc5c(cc4N(c4ccc(C(C)(C)C)cc4-c4ccccc4)c4cc(-c6ccccc6)cc(c43)-c3ccc(N(c4ccc(C(C)(C)C)cc4)c4ccc(C(C)(C)C)cc4)cc32)-c2ccccc2C5(C)C)cc1 ; CC(C)(C)c1ccc(N2B3c4c(cc(-c5ccccc5)cc4N(c4ccc(C(C)(C)C)cc4-c4ccccc4)c4ccc5sc6ccccc6c5c43)-c3cc(N(c4ccc(C(C)(C)C)cc4)c4ccc(C(C)(C)C)cc4)ccc32)cc1] 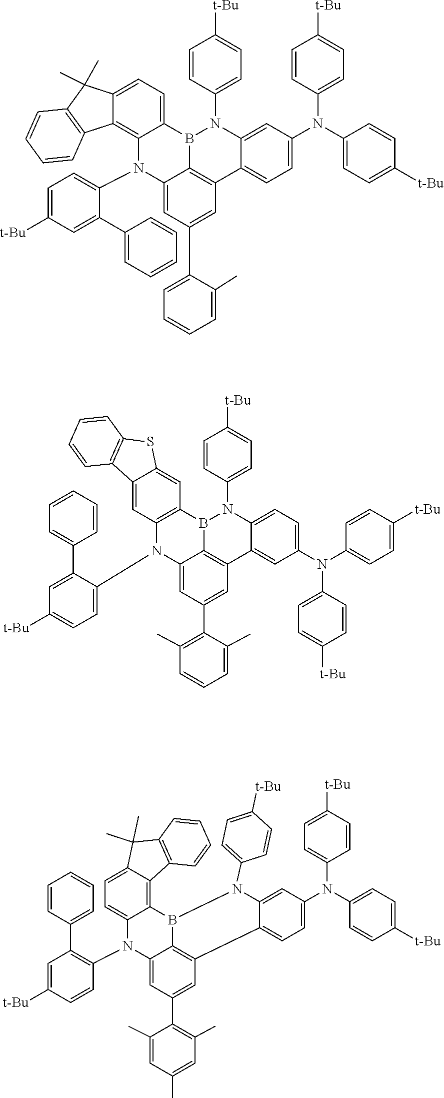 [SMILES: Cc1ccccc1-c1cc2c3c(c1)N(c1ccc(C(C)(C)C)cc1-c1ccccc1)c1c(ccc4c1-c1ccccc1C4(C)C)B3N(c1ccc(C(C)(C)C)cc1)c1cc(N(c3ccc(C(C)(C)C)cc3)c3ccc(C(C)(C)C)cc3)ccc1-2 ; Cc1cccc(C)c1-c1cc2c3c(c1)N(c1ccc(C(C)(C)C)cc1-c1ccccc1)c1cc4c(cc1B3N(c1ccc(C(C)(C)C)cc1)c1ccc(N(c3ccc(C(C)(C)C)cc3)c3ccc(C(C)(C)C)cc3)cc1-2)sc1ccccc14 ; Cc1cc(C)c(-c2cc3c4c(c2)N(c2ccc(C(C)(C)C)cc2-c2ccccc2)c2ccc5c(c2B4N(c2ccc(C(C)(C)C)cc2)c2cc(N(c4ccc(C(C)(C)C)cc4)c4ccc(C(C)(C)C)cc4)ccc2-3)-c2ccccc2C5(C)C)c(C)c1] 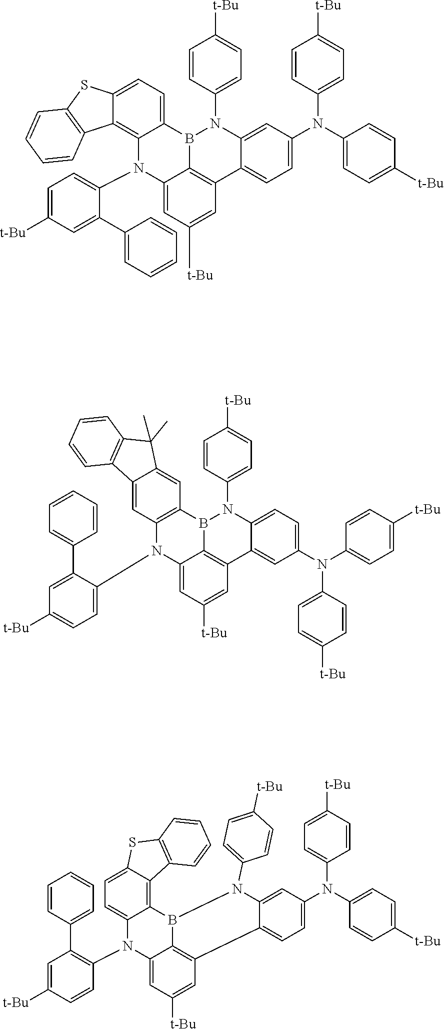 [SMILES: CC(C)(C)c1ccc(N2B3c4ccc5sc6ccccc6c5c4N(c4ccc(C(C)(C)C)cc4-c4ccccc4)c4cc(C(C)(C)C)cc(c43)-c3ccc(N(c4ccc(C(C)(C)C)cc4)c4ccc(C(C)(C)C)cc4)cc32)cc1 ; CC(C)(C)c1ccc(N2B3c4cc5c(cc4N(c4ccc(C(C)(C)C)cc4-c4ccccc4)c4cc(C(C)(C)C)cc(c43)-c3cc(N(c4ccc(C(C)(C)C)cc4)c4ccc(C(C)(C)C)cc4)ccc32)-c2ccccc2C5(C)C)cc1 ; CC(C)(C)c1ccc(N2B3c4c(cc(C(C)(C)C)cc4N(c4ccc(C(C)(C)C)cc4-c4ccccc4)c4ccc5sc6ccccc6c5c43)-c3ccc(N(c4ccc(C(C)(C)C)cc4)c4ccc(C(C)(C)C)cc4)cc32)cc1] 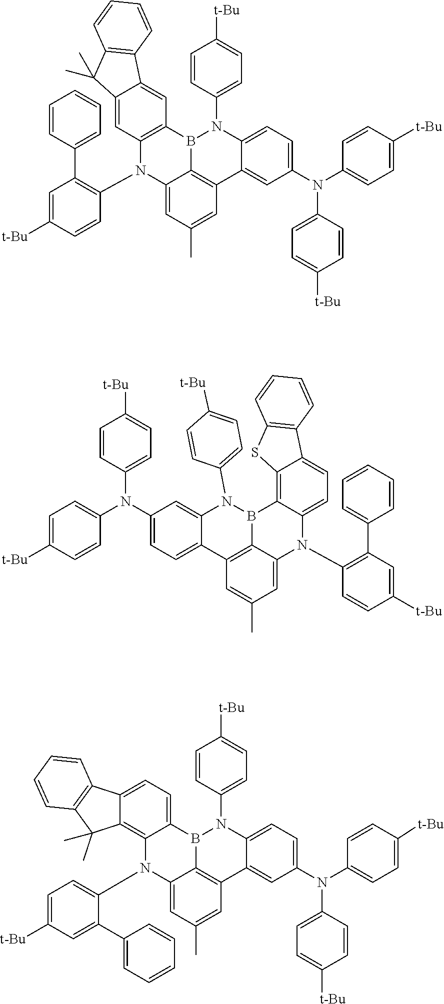 [SMILES: Cc1cc2c3c(c1)N(c1ccc(C(C)(C)C)cc1-c1ccccc1)c1cc4c(cc1B3N(c1ccc(C(C)(C)C)cc1)c1ccc(N(c3ccc(C(C)(C)C)cc3)c3ccc(C(C)(C)C)cc3)cc1-2)-c1ccccc1C4(C)C ; Cc1cc2c3c(c1)N(c1ccc(C(C)(C)C)cc1-c1ccccc1)c1ccc4c(sc5ccccc54)c1B3N(c1ccc(C(C)(C)C)cc1)c1cc(N(c3ccc(C(C)(C)C)cc3)c3ccc(C(C)(C)C)cc3)ccc1-2 ; Cc1cc2c3c(c1)N(c1ccc(C(C)(C)C)cc1-c1ccccc1)c1c(ccc4c1C(C)(C)c1ccccc1-4)B3N(c1ccc(C(C)(C)C)cc1)c1ccc(N(c3ccc(C(C)(C)C)cc3)c3ccc(C(C)(C)C)cc3)cc1-2] 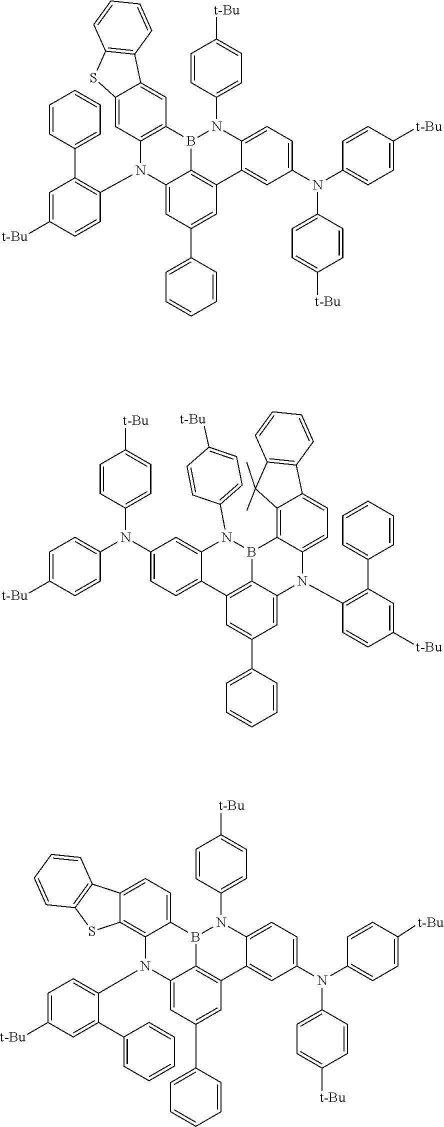 [SMILES: CC(C)(C)c1ccc(N2B3c4cc5c(cc4N(c4ccc(C(C)(C)C)cc4-c4ccccc4)c4cc(-c6ccccc6)cc(c43)-c3cc(N(c4ccc(C(C)(C)C)cc4)c4ccc(C(C)(C)C)cc4)ccc32)sc2ccccc25)cc1 ; CC(C)(C)c1ccc(N2B3c4c(cc(-c5ccccc5)cc4N(c4ccc(C(C)(C)C)cc4-c4ccccc4)c4ccc5c(c43)C(C)(C)c3ccccc3-5)-c3ccc(N(c4ccc(C(C)(C)C)cc4)c4ccc(C(C)(C)C)cc4)cc32)cc1 ; CC(C)(C)c1ccc(N2B3c4ccc5c(sc6ccccc65)c4N(c4ccc(C(C)(C)C)cc4-c4ccccc4)c4cc(-c5ccccc5)cc(c43)-c3cc(N(c4ccc(C(C)(C)C)cc4)c4ccc(C(C)(C)C)cc4)ccc32)cc1] 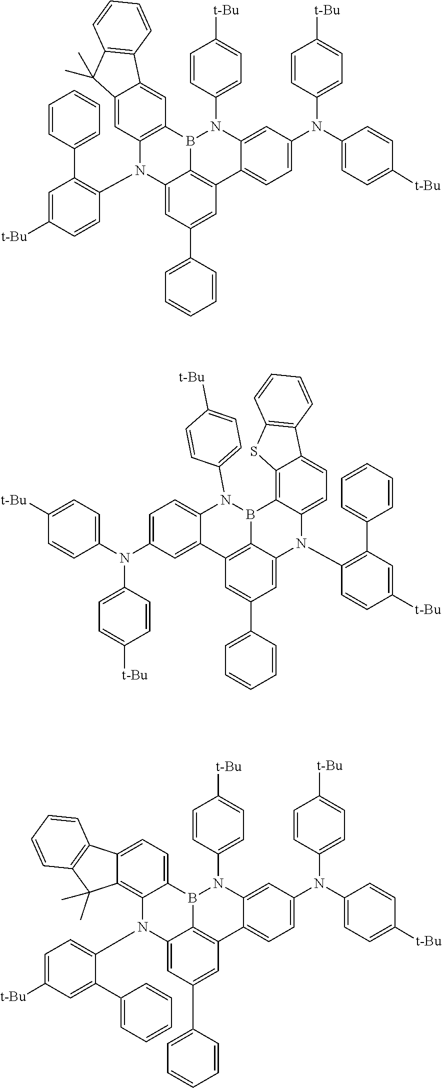 [SMILES: CC(C)(C)c1ccc(N2B3c4cc5c(cc4N(c4ccc(C(C)(C)C)cc4-c4ccccc4)c4cc(-c6ccccc6)cc(c43)-c3ccc(N(c4ccc(C(C)(C)C)cc4)c4ccc(C(C)(C)C)cc4)cc32)C(C)(C)c2ccccc2-5)cc1 ; CC(C)(C)c1ccc(N2B3c4c(cc(-c5ccccc5)cc4N(c4ccc(C(C)(C)C)cc4-c4ccccc4)c4ccc5c(sc6ccccc65)c43)-c3cc(N(c4ccc(C(C)(C)C)cc4)c4ccc(C(C)(C)C)cc4)ccc32)cc1 ; CC(C)(C)c1ccc(N2B3c4ccc5c(c4N(c4ccc(C(C)(C)C)cc4-c4ccccc4)c4cc(-c6ccccc6)cc(c43)-c3ccc(N(c4ccc(C(C)(C)C)cc4)c4ccc(C(C)(C)C)cc4)cc32)C(C)(C)c2ccccc2-5)cc1] 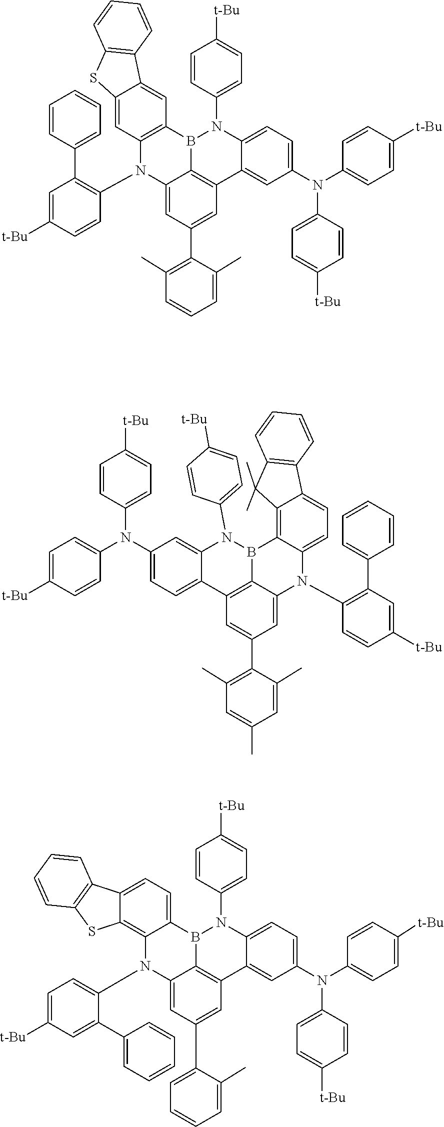 [SMILES: Cc1cccc(C)c1-c1cc2c3c(c1)N(c1ccc(C(C)(C)C)cc1-c1ccccc1)c1cc4sc5ccccc5c4cc1B3N(c1ccc(C(C)(C)C)cc1)c1ccc(N(c3ccc(C(C)(C)C)cc3)c3ccc(C(C)(C)C)cc3)cc1-2 ; Cc1cc(C)c(-c2cc3c4c(c2)N(c2ccc(C(C)(C)C)cc2-c2ccccc2)c2ccc5c(c2B4N(c2ccc(C(C)(C)C)cc2)c2cc(N(c4ccc(C(C)(C)C)cc4)c4ccc(C(C)(C)C)cc4)ccc2-3)C(C)(C)c2ccccc2-5)c(C)c1 ; Cc1ccccc1-c1cc2c3c(c1)N(c1ccc(C(C)(C)C)cc1-c1ccccc1)c1c(ccc4c1sc1ccccc14)B3N(c1ccc(C(C)(C)C)cc1)c1ccc(N(c3ccc(C(C)(C)C)cc3)c3ccc(C(C)(C)C)cc3)cc1-2] 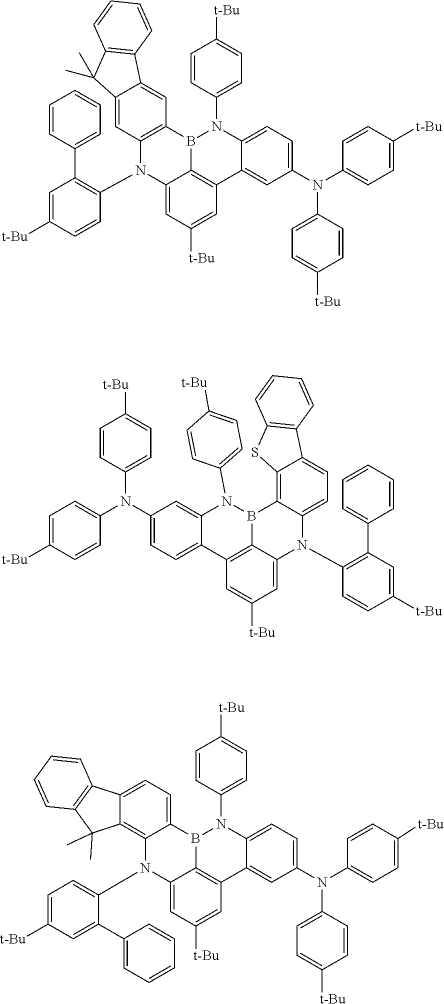 [SMILES: CC(C)(C)c1ccc(N2B3c4cc5c(cc4N(c4ccc(C(C)(C)C)cc4-c4ccccc4)c4cc(C(C)(C)C)cc(c43)-c3cc(N(c4ccc(C(C)(C)C)cc4)c4ccc(C(C)(C)C)cc4)ccc32)C(C)(C)c2ccccc2-5)cc1 ; CC(C)(C)c1ccc(N2B3c4c(cc(C(C)(C)C)cc4N(c4ccc(C(C)(C)C)cc4-c4ccccc4)c4ccc5c(sc6ccccc65)c43)-c3ccc(N(c4ccc(C(C)(C)C)cc4)c4ccc(C(C)(C)C)cc4)cc32)cc1 ; CC(C)(C)c1ccc(N2B3c4ccc5c(c4N(c4ccc(C(C)(C)C)cc4-c4ccccc4)c4cc(C(C)(C)C)cc(c43)-c3cc(N(c4ccc(C(C)(C)C)cc4)c4ccc(C(C)(C)C)cc4)ccc32)C(C)(C)c2ccccc2-5)cc1] 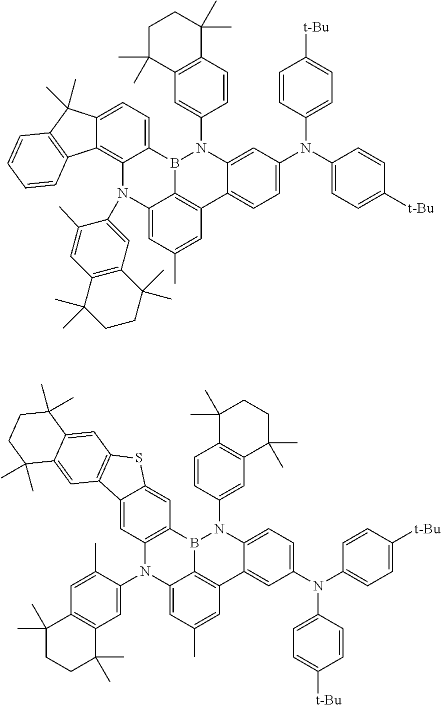 [SMILES: Cc1cc2c3c(c1)N(c1cc4c(cc1C)C(C)(C)CCC4(C)C)c1c(ccc4c1-c1ccccc1C4(C)C)B3N(c1ccc3c(c1)C(C)(C)CCC3(C)C)c1cc(N(c3ccc(C(C)(C)C)cc3)c3ccc(C(C)(C)C)cc3)ccc1-2 ; Cc1cc2c3c(c1)N(c1cc4c(cc1C)C(C)(C)CCC4(C)C)c1cc4c(cc1B3N(c1ccc3c(c1)C(C)(C)CCC3(C)C)c1ccc(N(c3ccc(C(C)(C)C)cc3)c3ccc(C(C)(C)C)cc3)cc1-2)sc1cc2c(cc14)C(C)(C)CCC2(C)C] 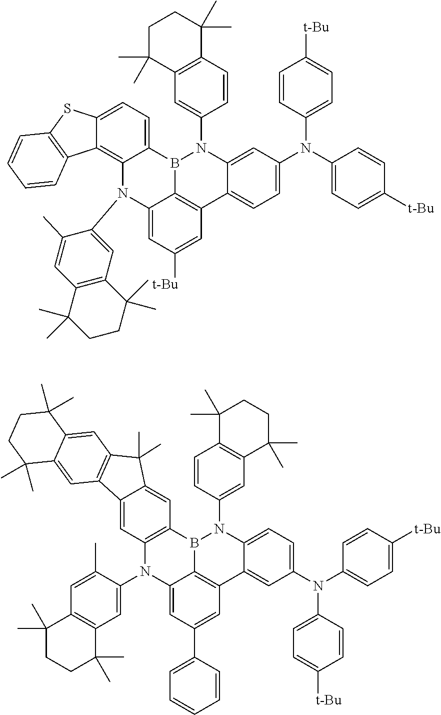 [SMILES: Cc1cc2c(cc1N1c3cc(C(C)(C)C)cc4c3B(c3ccc5sc6ccccc6c5c31)N(c1ccc3c(c1)C(C)(C)CCC3(C)C)c1cc(N(c3ccc(C(C)(C)C)cc3)c3ccc(C(C)(C)C)cc3)ccc1-4)C(C)(C)CCC2(C)C ; Cc1cc2c(cc1N1c3cc4c(cc3B3c5c(cc(-c6ccccc6)cc51)-c1cc(N(c5ccc(C(C)(C)C)cc5)c5ccc(C(C)(C)C)cc5)ccc1N3c1ccc3c(c1)C(C)(C)CCC3(C)C)C(C)(C)c1cc3c(cc1-4)C(C)(C)CCC3(C)C)C(C)(C)CCC2(C)C] 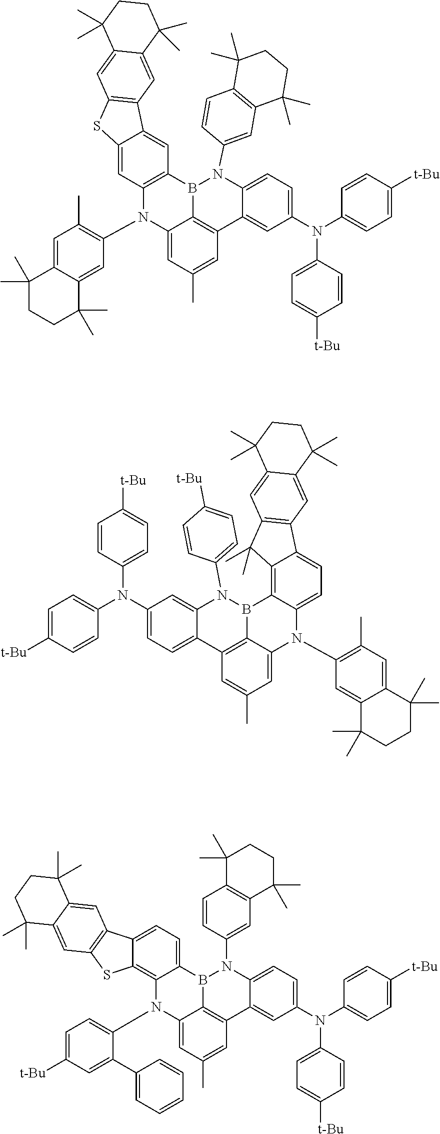 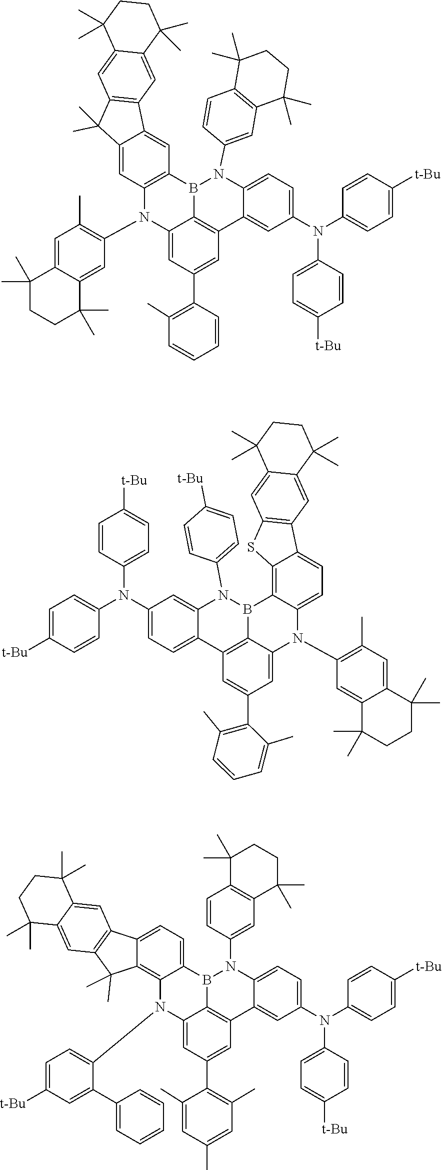 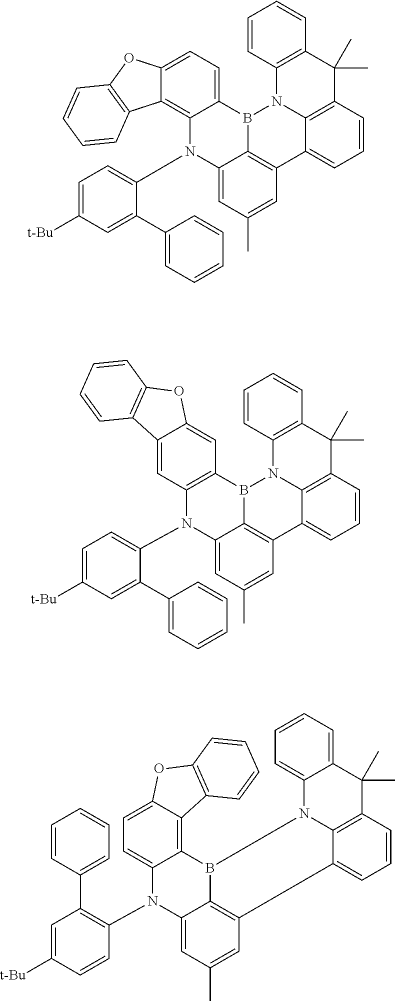 [SMILES: Cc1cc2c3c(c1)N(c1ccc(C(C)(C)C)cc1-c1ccccc1)c1c(ccc4oc5ccccc5c14)B3N1c3ccccc3C(C)(C)c3cccc-2c31 ; Cc1cc2c3c(c1)N(c1ccc(C(C)(C)C)cc1-c1ccccc1)c1cc4c(cc1B3N1c3ccccc3C(C)(C)c3cccc-2c31)oc1ccccc14 ; Cc1cc2c3c(c1)N(c1ccc(C(C)(C)C)cc1-c1ccccc1)c1ccc4oc5ccccc5c4c1B3N1c3ccccc3C(C)(C)c3cccc-2c31] 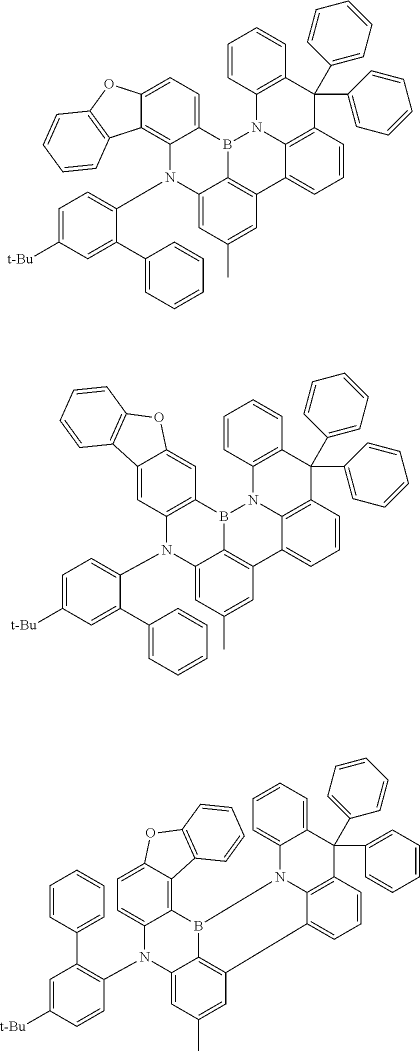 [SMILES: Cc1cc2c3c(c1)N(c1ccc(C(C)(C)C)cc1-c1ccccc1)c1c(ccc4oc5ccccc5c14)B3N1c3ccccc3C(c3ccccc3)(c3ccccc3)c3cccc-2c31 ; Cc1cc2c3c(c1)N(c1ccc(C(C)(C)C)cc1-c1ccccc1)c1cc4c(cc1B3N1c3ccccc3C(c3ccccc3)(c3ccccc3)c3cccc-2c31)oc1ccccc14 ; Cc1cc2c3c(c1)N(c1ccc(C(C)(C)C)cc1-c1ccccc1)c1ccc4oc5ccccc5c4c1B3N1c3ccccc3C(c3ccccc3)(c3ccccc3)c3cccc-2c31] 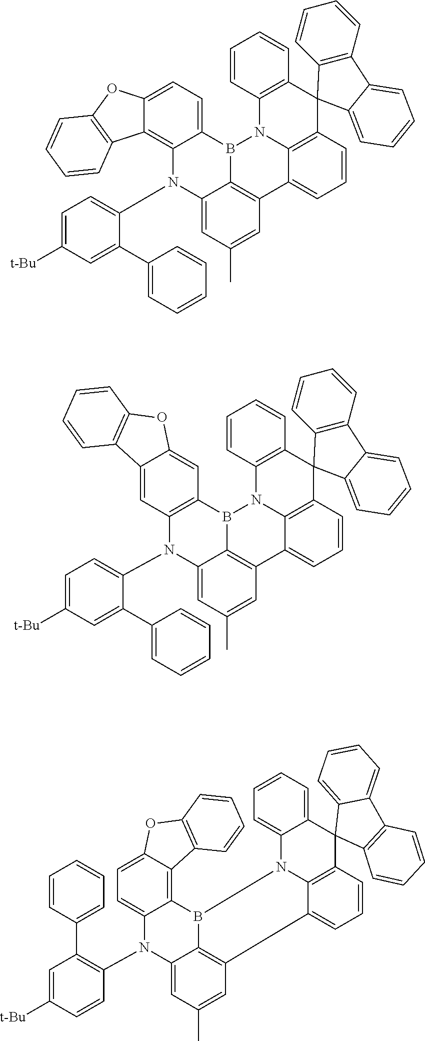 [SMILES: Cc1cc2c3c(c1)N(c1ccc(C(C)(C)C)cc1-c1ccccc1)c1c(ccc4oc5ccccc5c14)B3N1c3ccccc3C3(c4ccccc4-c4ccccc43)c3cccc-2c31 ; Cc1cc2c3c(c1)N(c1ccc(C(C)(C)C)cc1-c1ccccc1)c1cc4c(cc1B3N1c3ccccc3C3(c5ccccc5-c5ccccc53)c3cccc-2c31)oc1ccccc14 ; Cc1cc2c3c(c1)N(c1ccc(C(C)(C)C)cc1-c1ccccc1)c1ccc4oc5ccccc5c4c1B3N1c3ccccc3C3(c4ccccc4-c4ccccc43)c3cccc-2c31] 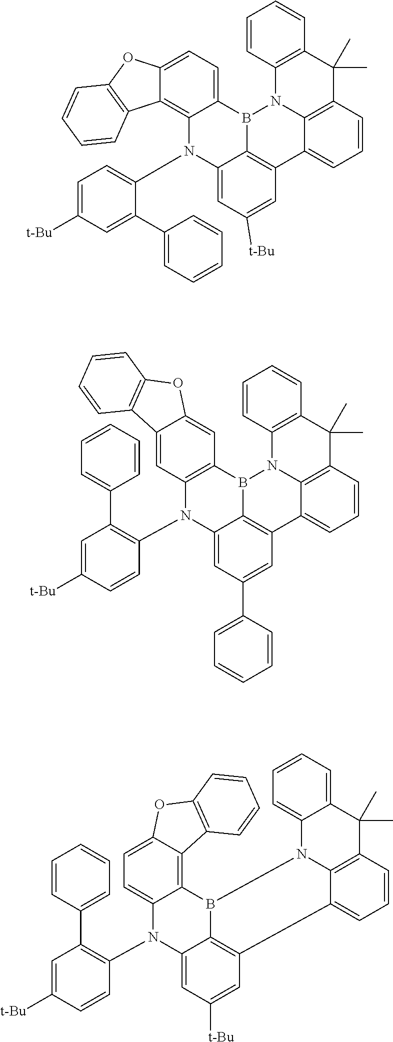 [SMILES: CC(C)(C)c1ccc(N2c3cc(C(C)(C)C)cc4c3B(c3ccc5oc6ccccc6c5c32)N2c3ccccc3C(C)(C)c3cccc-4c32)c(-c2ccccc2)c1 ; CC(C)(C)c1ccc(N2c3cc4c(cc3B3c5c(cc(-c6ccccc6)cc52)-c2cccc5c2N3c2ccccc2C5(C)C)oc2ccccc24)c(-c2ccccc2)c1 ; CC(C)(C)c1ccc(N2c3cc(C(C)(C)C)cc4c3B(c3c2ccc2oc5ccccc5c32)N2c3ccccc3C(C)(C)c3cccc-4c32)c(-c2ccccc2)c1] 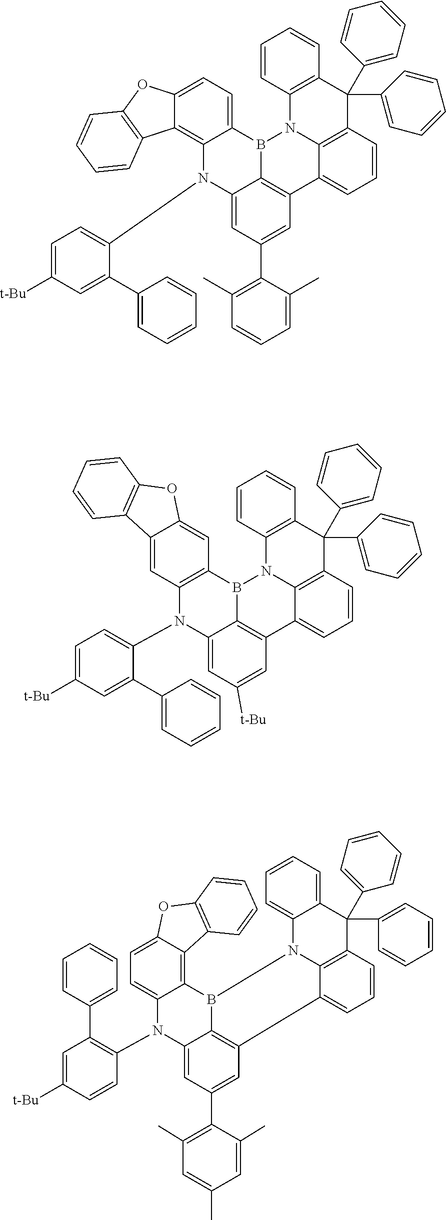 [SMILES: Cc1cccc(C)c1-c1cc2c3c(c1)N(c1ccc(C(C)(C)C)cc1-c1ccccc1)c1c(ccc4oc5ccccc5c14)B3N1c3ccccc3C(c3ccccc3)(c3ccccc3)c3cccc-2c31 ; CC(C)(C)c1ccc(N2c3cc4c(cc3B3c5c(cc(C(C)(C)C)cc52)-c2cccc5c2N3c2ccccc2C5(c2ccccc2)c2ccccc2)oc2ccccc24)c(-c2ccccc2)c1 ; Cc1cc(C)c(-c2cc3c4c(c2)N(c2ccc(C(C)(C)C)cc2-c2ccccc2)c2ccc5oc6ccccc6c5c2B4N2c4ccccc4C(c4ccccc4)(c4ccccc4)c4cccc-3c42)c(C)c1] 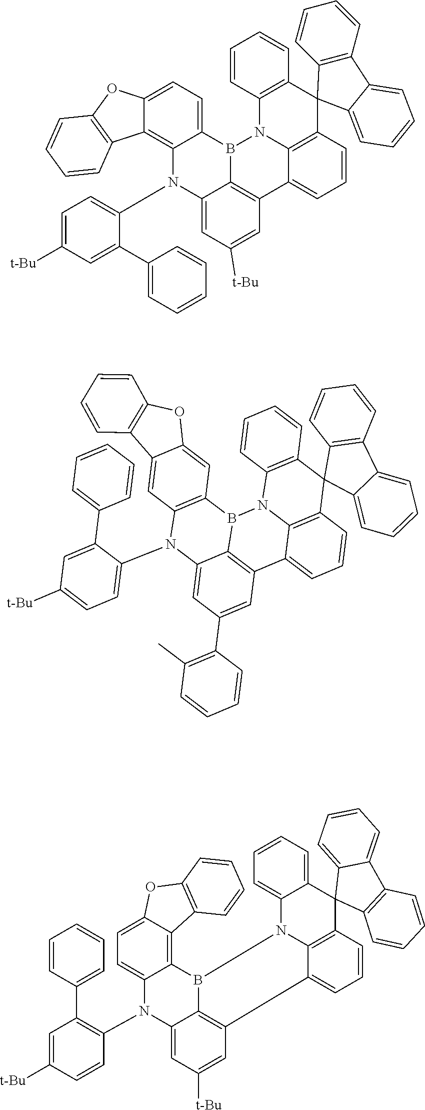 [SMILES: CC(C)(C)c1ccc(N2c3cc(C(C)(C)C)cc4c3B(c3ccc5oc6ccccc6c5c32)N2c3ccccc3C3(c5ccccc5-c5ccccc53)c3cccc-4c32)c(-c2ccccc2)c1 ; Cc1ccccc1-c1cc2c3c(c1)N(c1ccc(C(C)(C)C)cc1-c1ccccc1)c1cc4c(cc1B3N1c3ccccc3C3(c5ccccc5-c5ccccc53)c3cccc-2c31)oc1ccccc14 ; CC(C)(C)c1ccc(N2c3cc(C(C)(C)C)cc4c3B(c3c2ccc2oc5ccccc5c32)N2c3ccccc3C3(c5ccccc5-c5ccccc53)c3cccc-4c32)c(-c2ccccc2)c1] 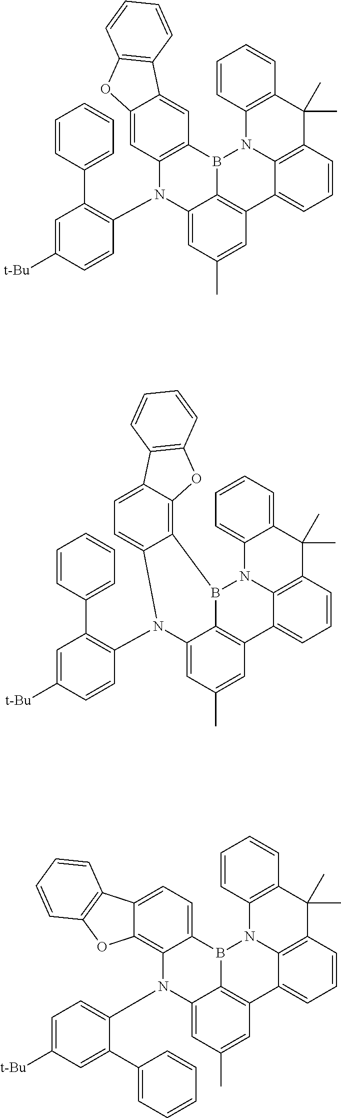 [SMILES: Cc1cc2c3c(c1)N(c1ccc(C(C)(C)C)cc1-c1ccccc1)c1cc4oc5ccccc5c4cc1B3N1c3ccccc3C(C)(C)c3cccc-2c31 ; Cc1cc2c3c(c1)N(c1ccc(C(C)(C)C)cc1-c1ccccc1)c1ccc4c(oc5ccccc54)c1B3N1c3ccccc3C(C)(C)c3cccc-2c31 ; Cc1cc2c3c(c1)N(c1ccc(C(C)(C)C)cc1-c1ccccc1)c1c(ccc4c1oc1ccccc14)B3N1c3ccccc3C(C)(C)c3cccc-2c31] 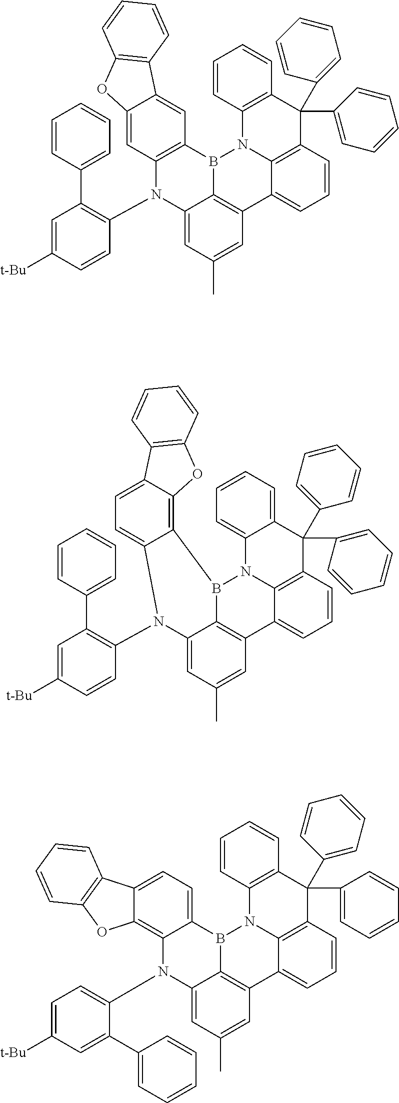 [SMILES: Cc1cc2c3c(c1)N(c1ccc(C(C)(C)C)cc1-c1ccccc1)c1cc4oc5ccccc5c4cc1B3N1c3ccccc3C(c3ccccc3)(c3ccccc3)c3cccc-2c31 ; Cc1cc2c3c(c1)N(c1ccc(C(C)(C)C)cc1-c1ccccc1)c1ccc4c(oc5ccccc54)c1B3N1c3ccccc3C(c3ccccc3)(c3ccccc3)c3cccc-2c31 ; Cc1cc2c3c(c1)N(c1ccc(C(C)(C)C)cc1-c1ccccc1)c1c(ccc4c1oc1ccccc14)B3N1c3ccccc3C(c3ccccc3)(c3ccccc3)c3cccc-2c31] 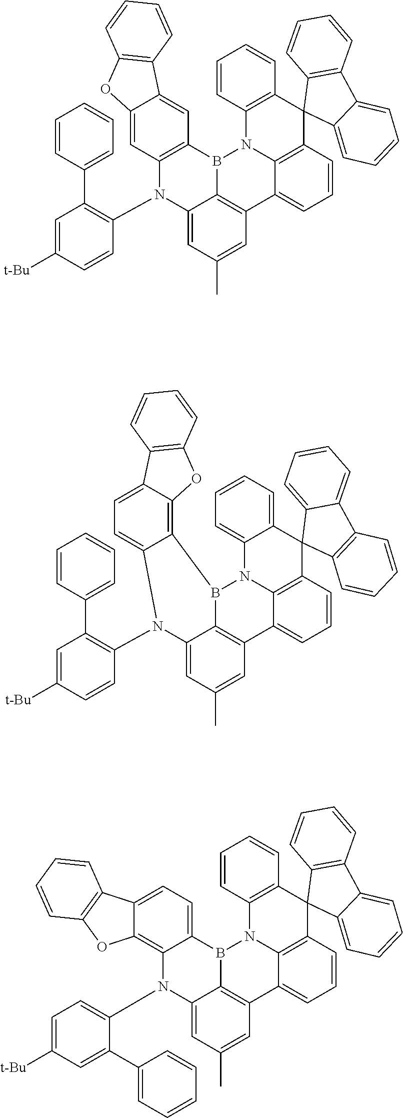 [SMILES: Cc1cc2c3c(c1)N(c1ccc(C(C)(C)C)cc1-c1ccccc1)c1cc4oc5ccccc5c4cc1B3N1c3ccccc3C3(c4ccccc4-c4ccccc43)c3cccc-2c31 ; Cc1cc2c3c(c1)N(c1ccc(C(C)(C)C)cc1-c1ccccc1)c1ccc4c(oc5ccccc54)c1B3N1c3ccccc3C3(c4ccccc4-c4ccccc43)c3cccc-2c31 ; Cc1cc2c3c(c1)N(c1ccc(C(C)(C)C)cc1-c1ccccc1)c1c(ccc4c1oc1ccccc14)B3N1c3ccccc3C3(c4ccccc4-c4ccccc43)c3cccc-2c31] 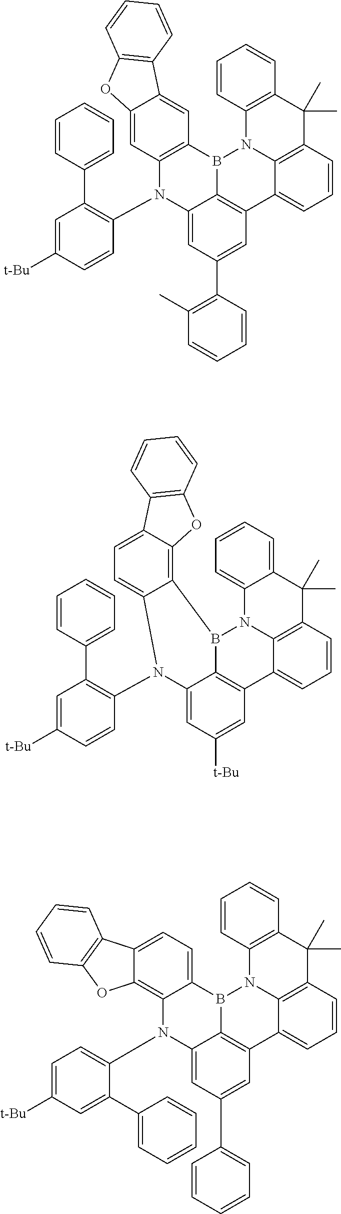 [SMILES: Cc1ccccc1-c1cc2c3c(c1)N(c1ccc(C(C)(C)C)cc1-c1ccccc1)c1cc4oc5ccccc5c4cc1B3N1c3ccccc3C(C)(C)c3cccc-2c31 ; CC(C)(C)c1ccc(N2c3cc(C(C)(C)C)cc4c3B(c3c2ccc2c3oc3ccccc32)N2c3ccccc3C(C)(C)c3cccc-4c32)c(-c2ccccc2)c1 ; CC(C)(C)c1ccc(N2c3cc(-c4ccccc4)cc4c3B(c3ccc5c(oc6ccccc65)c32)N2c3ccccc3C(C)(C)c3cccc-4c32)c(-c2ccccc2)c1] 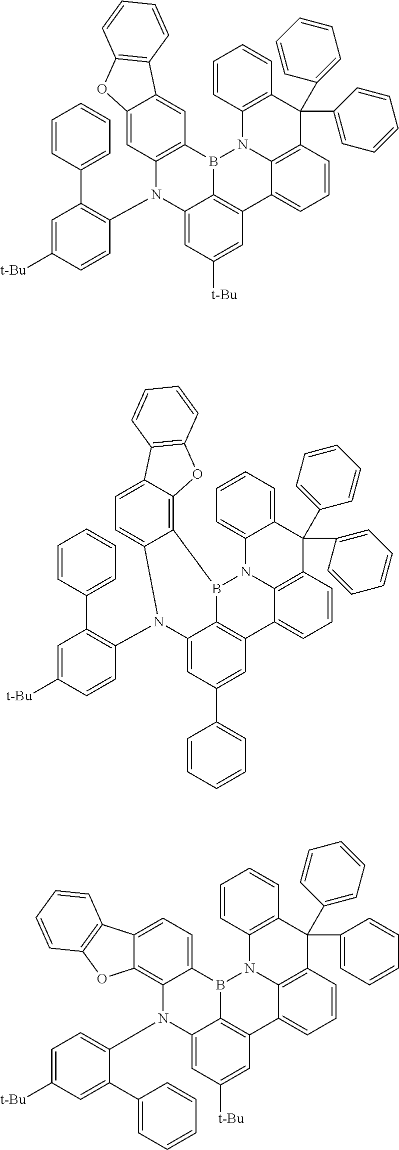 [SMILES: CC(C)(C)c1ccc(N2c3cc4oc5ccccc5c4cc3B3c4c(cc(C(C)(C)C)cc42)-c2cccc4c2N3c2ccccc2C4(c2ccccc2)c2ccccc2)c(-c2ccccc2)c1 ; CC(C)(C)c1ccc(N2c3cc(-c4ccccc4)cc4c3B(c3c2ccc2c3oc3ccccc32)N2c3ccccc3C(c3ccccc3)(c3ccccc3)c3cccc-4c32)c(-c2ccccc2)c1 ; CC(C)(C)c1ccc(N2c3cc(C(C)(C)C)cc4c3B(c3ccc5c(oc6ccccc65)c32)N2c3ccccc3C(c3ccccc3)(c3ccccc3)c3cccc-4c32)c(-c2ccccc2)c1] 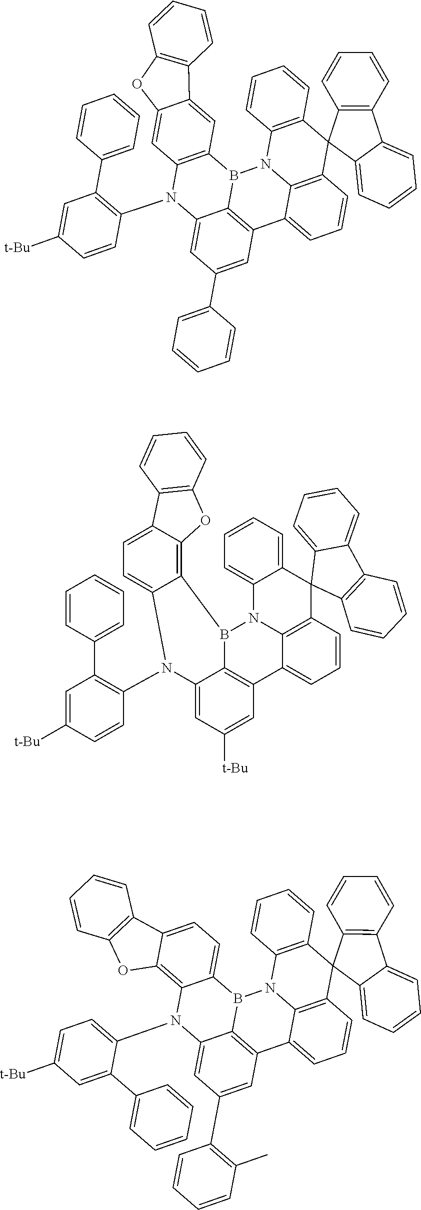 [SMILES: CC(C)(C)c1ccc(N2c3cc4oc5ccccc5c4cc3B3c4c(cc(-c5ccccc5)cc42)-c2cccc4c2N3c2ccccc2C42c3ccccc3-c3ccccc32)c(-c2ccccc2)c1 ; CC(C)(C)c1ccc(N2c3cc(C(C)(C)C)cc4c3B(c3c2ccc2c3oc3ccccc32)N2c3ccccc3C3(c5ccccc5-c5ccccc53)c3cccc-4c32)c(-c2ccccc2)c1 ; Cc1ccccc1-c1cc2c3c(c1)N(c1ccc(C(C)(C)C)cc1-c1ccccc1)c1c(ccc4c1oc1ccccc14)B3N1c3ccccc3C3(c4ccccc4-c4ccccc43)c3cccc-2c31] 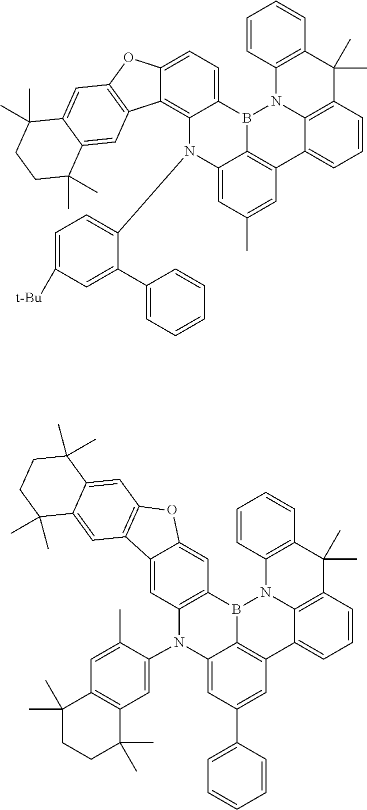 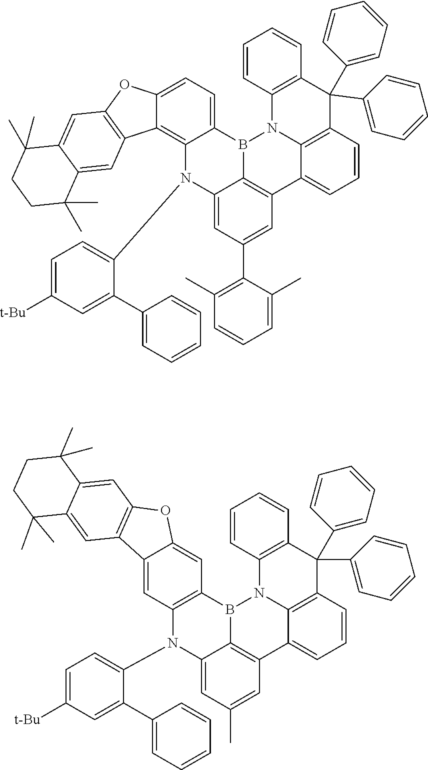 [SMILES: Cc1cccc(C)c1-c1cc2c3c(c1)N(c1ccc(C(C)(C)C)cc1-c1ccccc1)c1c(ccc4oc5cc6c(cc5c14)C(C)(C)CCC6(C)C)B3N1c3ccccc3C(c3ccccc3)(c3ccccc3)c3cccc-2c31 ; Cc1cc2c3c(c1)N(c1ccc(C(C)(C)C)cc1-c1ccccc1)c1cc4c(cc1B3N1c3ccccc3C(c3ccccc3)(c3ccccc3)c3cccc-2c31)oc1cc2c(cc14)C(C)(C)CCC2(C)C] 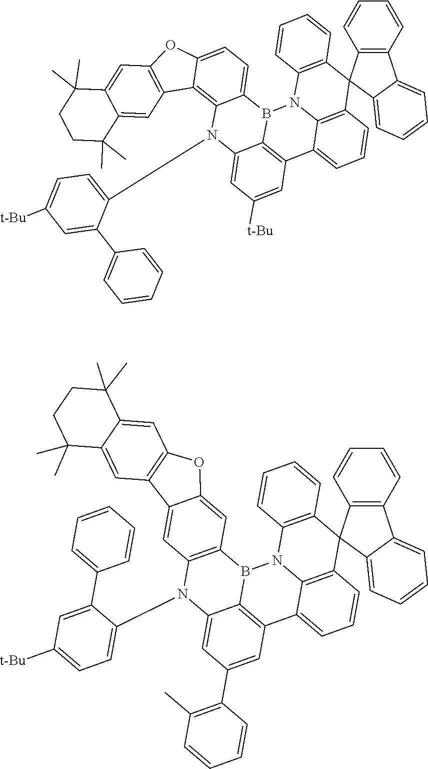 [SMILES: CC(C)(C)c1ccc(N2c3cc(C(C)(C)C)cc4c3B(c3ccc5oc6cc7c(cc6c5c32)C(C)(C)CCC7(C)C)N2c3ccccc3C3(c5ccccc5-c5ccccc53)c3cccc-4c32)c(-c2ccccc2)c1 ; Cc1ccccc1-c1cc2c3c(c1)N(c1ccc(C(C)(C)C)cc1-c1ccccc1)c1cc4c(cc1B3N1c3ccccc3C3(c5ccccc5-c5ccccc53)c3cccc-2c31)oc1cc2c(cc14)C(C)(C)CCC2(C)C] 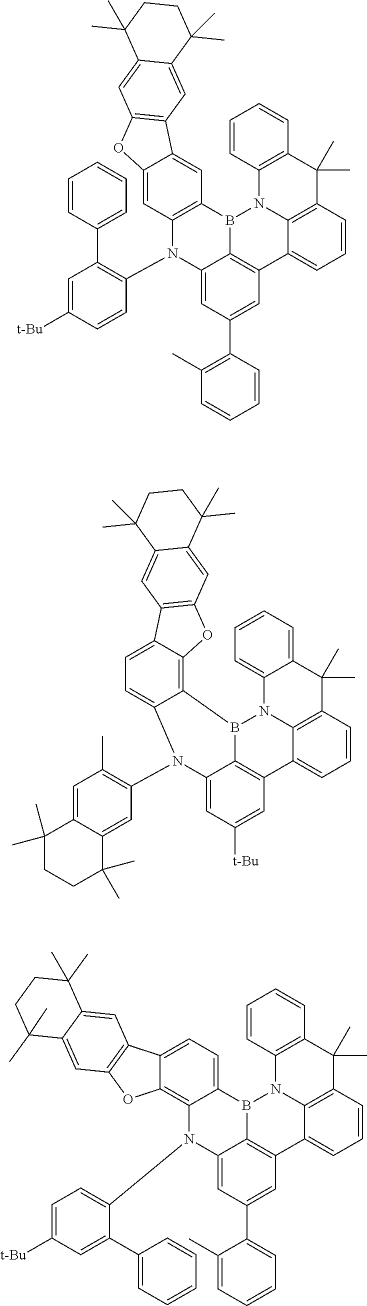 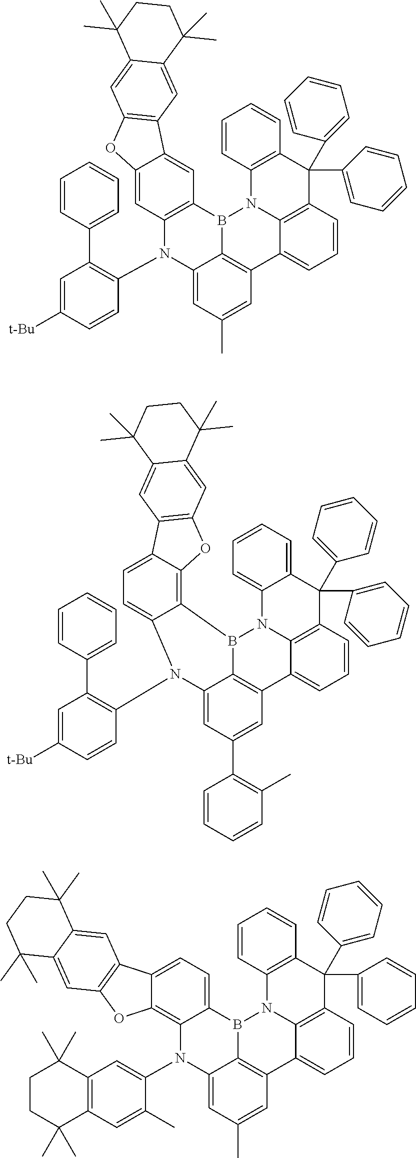 [SMILES: Cc1cc2c3c(c1)N(c1ccc(C(C)(C)C)cc1-c1ccccc1)c1cc4oc5cc6c(cc5c4cc1B3N1c3ccccc3C(c3ccccc3)(c3ccccc3)c3cccc-2c31)C(C)(C)CCC6(C)C ; Cc1ccccc1-c1cc2c3c(c1)N(c1ccc(C(C)(C)C)cc1-c1ccccc1)c1ccc4c(oc5cc6c(cc54)C(C)(C)CCC6(C)C)c1B3N1c3ccccc3C(c3ccccc3)(c3ccccc3)c3cccc-2c31 ; Cc1cc2c3c(c1)N(c1cc4c(cc1C)C(C)(C)CCC4(C)C)c1c(ccc4c1oc1cc5c(cc14)C(C)(C)CCC5(C)C)B3N1c3ccccc3C(c3ccccc3)(c3ccccc3)c3cccc-2c31] 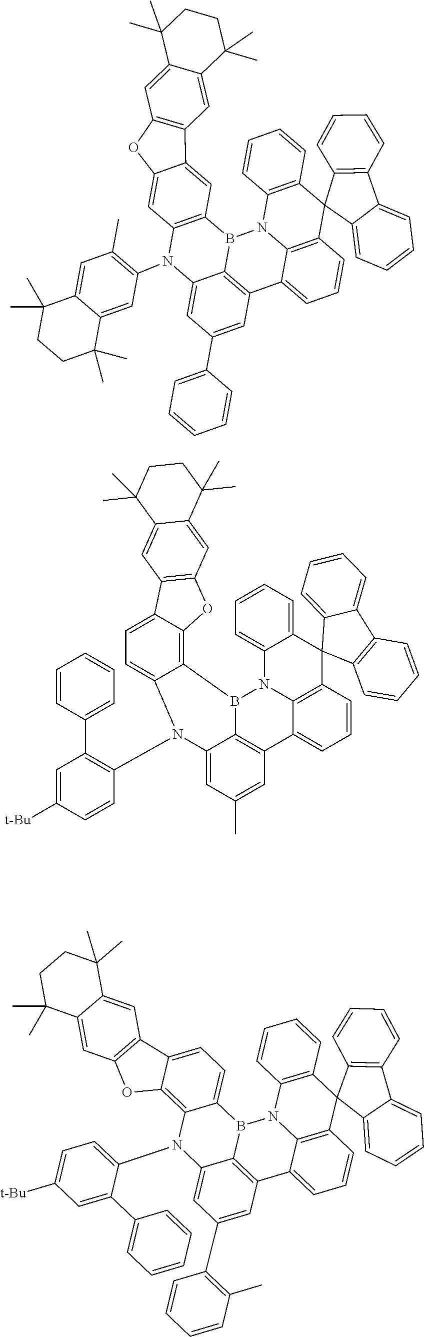 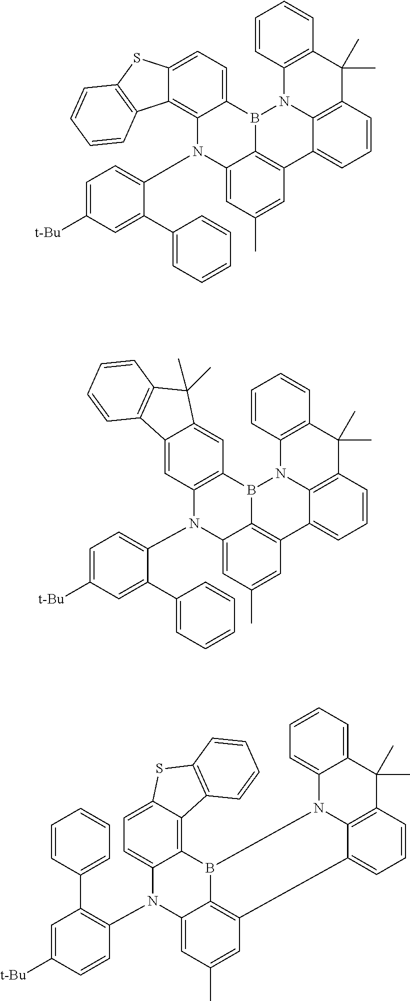 [SMILES: Cc1cc2c3c(c1)N(c1ccc(C(C)(C)C)cc1-c1ccccc1)c1c(ccc4sc5ccccc5c14)B3N1c3ccccc3C(C)(C)c3cccc-2c31 ; Cc1cc2c3c(c1)N(c1ccc(C(C)(C)C)cc1-c1ccccc1)c1cc4c(cc1B3N1c3ccccc3C(C)(C)c3cccc-2c31)C(C)(C)c1ccccc1-4 ; Cc1cc2c3c(c1)N(c1ccc(C(C)(C)C)cc1-c1ccccc1)c1ccc4sc5ccccc5c4c1B3N1c3ccccc3C(C)(C)c3cccc-2c31] 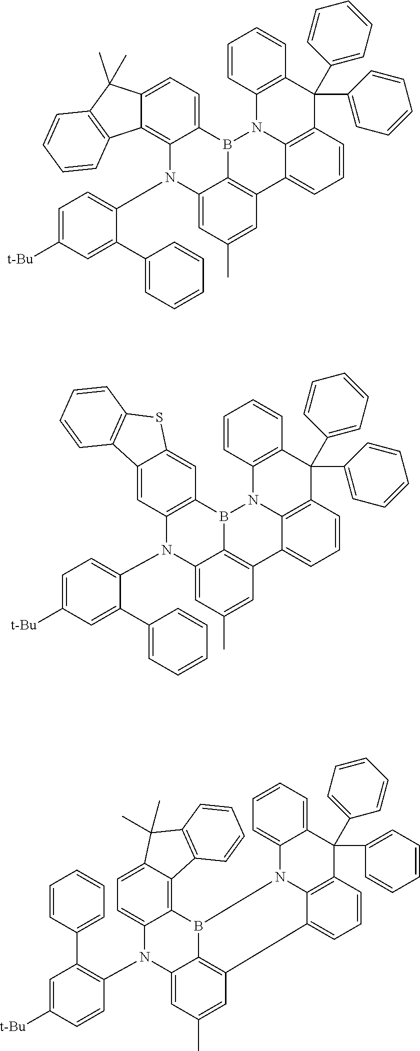 [SMILES: Cc1cc2c3c(c1)N(c1ccc(C(C)(C)C)cc1-c1ccccc1)c1c(ccc4c1-c1ccccc1C4(C)C)B3N1c3ccccc3C(c3ccccc3)(c3ccccc3)c3cccc-2c31 ; Cc1cc2c3c(c1)N(c1ccc(C(C)(C)C)cc1-c1ccccc1)c1cc4c(cc1B3N1c3ccccc3C(c3ccccc3)(c3ccccc3)c3cccc-2c31)sc1ccccc14 ; Cc1cc2c3c(c1)N(c1ccc(C(C)(C)C)cc1-c1ccccc1)c1ccc4c(c1B3N1c3ccccc3C(c3ccccc3)(c3ccccc3)c3cccc-2c31)-c1ccccc1C4(C)C] 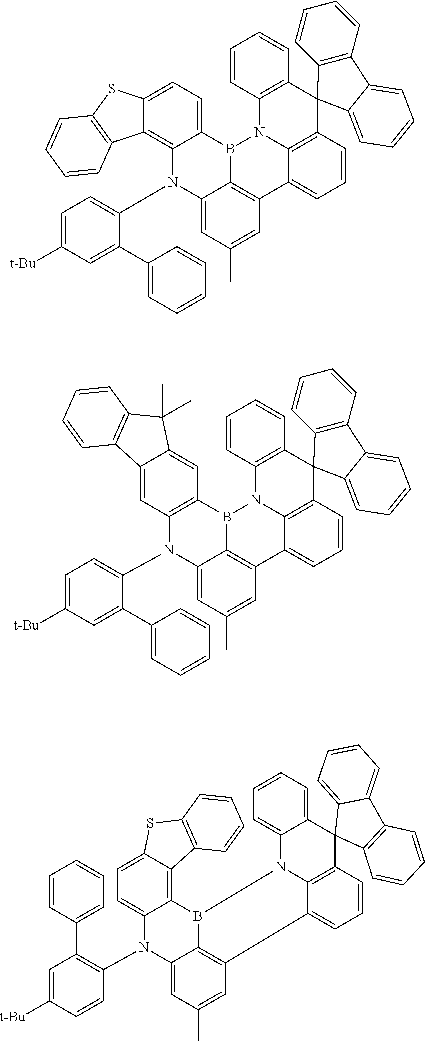 [SMILES: Cc1cc2c3c(c1)N(c1ccc(C(C)(C)C)cc1-c1ccccc1)c1c(ccc4sc5ccccc5c14)B3N1c3ccccc3C3(c4ccccc4-c4ccccc43)c3cccc-2c31 ; Cc1cc2c3c(c1)N(c1ccc(C(C)(C)C)cc1-c1ccccc1)c1cc4c(cc1B3N1c3ccccc3C3(c5ccccc5-c5ccccc53)c3cccc-2c31)C(C)(C)c1ccccc1-4 ; Cc1cc2c3c(c1)N(c1ccc(C(C)(C)C)cc1-c1ccccc1)c1ccc4sc5ccccc5c4c1B3N1c3ccccc3C3(c4ccccc4-c4ccccc43)c3cccc-2c31] 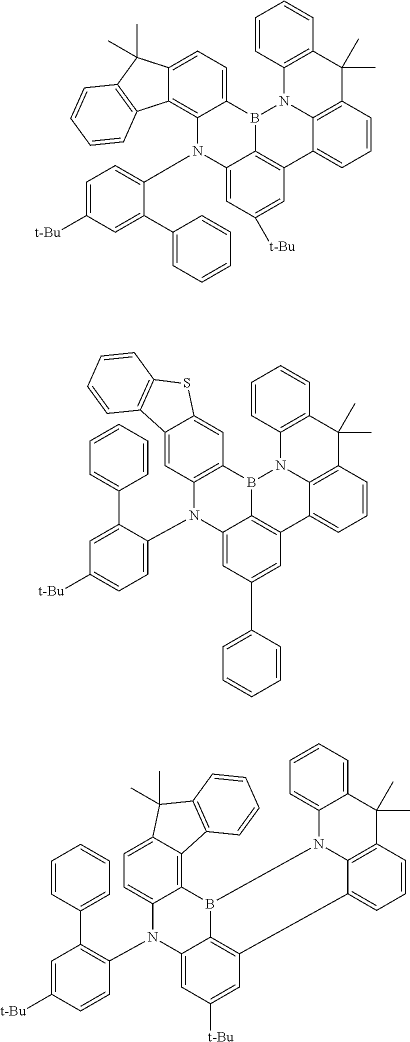 [SMILES: CC(C)(C)c1ccc(N2c3cc(C(C)(C)C)cc4c3B(c3ccc5c(c32)-c2ccccc2C5(C)C)N2c3ccccc3C(C)(C)c3cccc-4c32)c(-c2ccccc2)c1 ; CC(C)(C)c1ccc(N2c3cc4c(cc3B3c5c(cc(-c6ccccc6)cc52)-c2cccc5c2N3c2ccccc2C5(C)C)sc2ccccc24)c(-c2ccccc2)c1 ; CC(C)(C)c1ccc(N2c3cc(C(C)(C)C)cc4c3B(c3c2ccc2c3-c3ccccc3C2(C)C)N2c3ccccc3C(C)(C)c3cccc-4c32)c(-c2ccccc2)c1] 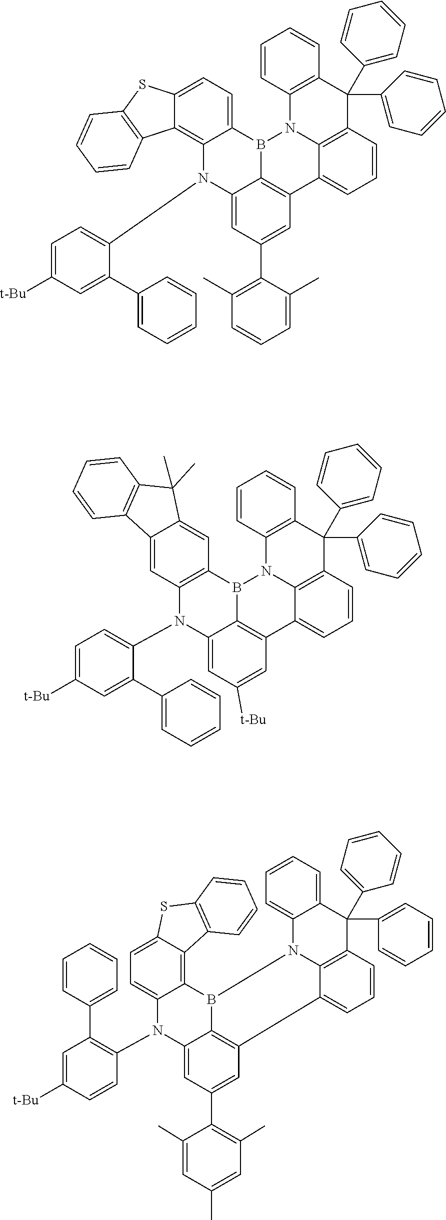 [SMILES: Cc1cccc(C)c1-c1cc2c3c(c1)N(c1ccc(C(C)(C)C)cc1-c1ccccc1)c1c(ccc4sc5ccccc5c14)B3N1c3ccccc3C(c3ccccc3)(c3ccccc3)c3cccc-2c31 ; CC(C)(C)c1ccc(N2c3cc4c(cc3B3c5c(cc(C(C)(C)C)cc52)-c2cccc5c2N3c2ccccc2C5(c2ccccc2)c2ccccc2)C(C)(C)c2ccccc2-4)c(-c2ccccc2)c1 ; Cc1cc(C)c(-c2cc3c4c(c2)N(c2ccc(C(C)(C)C)cc2-c2ccccc2)c2ccc5sc6ccccc6c5c2B4N2c4ccccc4C(c4ccccc4)(c4ccccc4)c4cccc-3c42)c(C)c1] 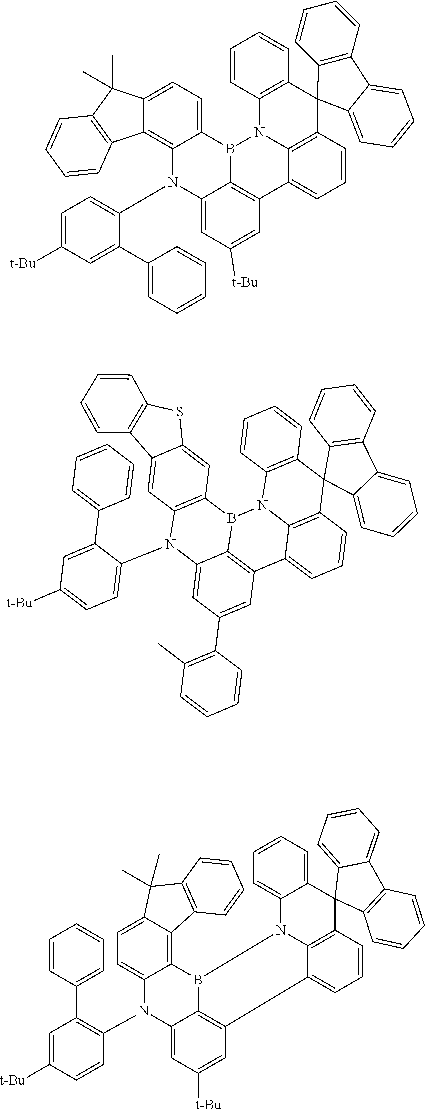 [SMILES: CC(C)(C)c1ccc(N2c3cc(C(C)(C)C)cc4c3B(c3ccc5c(c32)-c2ccccc2C5(C)C)N2c3ccccc3C3(c5ccccc5-c5ccccc53)c3cccc-4c32)c(-c2ccccc2)c1 ; Cc1ccccc1-c1cc2c3c(c1)N(c1ccc(C(C)(C)C)cc1-c1ccccc1)c1cc4c(cc1B3N1c3ccccc3C3(c5ccccc5-c5ccccc53)c3cccc-2c31)sc1ccccc14 ; CC(C)(C)c1ccc(N2c3cc(C(C)(C)C)cc4c3B(c3c2ccc2c3-c3ccccc3C2(C)C)N2c3ccccc3C3(c5ccccc5-c5ccccc53)c3cccc-4c32)c(-c2ccccc2)c1] 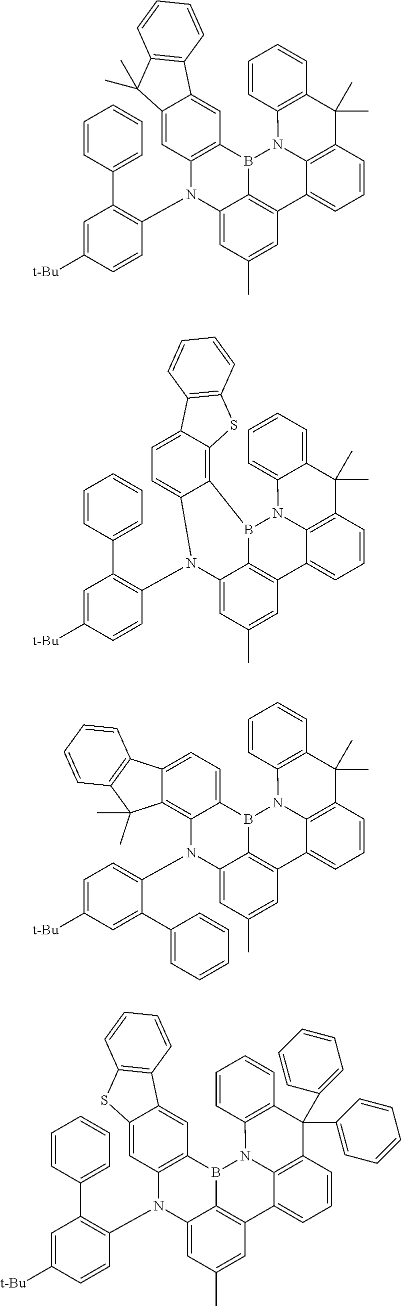 [SMILES: Cc1cc2c3c(c1)N(c1ccc(C(C)(C)C)cc1-c1ccccc1)c1cc4c(cc1B3N1c3ccccc3C(C)(C)c3cccc-2c31)-c1ccccc1C4(C)C ; Cc1cc2c3c(c1)N(c1ccc(C(C)(C)C)cc1-c1ccccc1)c1ccc4c(sc5ccccc54)c1B3N1c3ccccc3C(C)(C)c3cccc-2c31 ; Cc1cc2c3c(c1)N(c1ccc(C(C)(C)C)cc1-c1ccccc1)c1c(ccc4c1C(C)(C)c1ccccc1-4)B3N1c3ccccc3C(C)(C)c3cccc-2c31 ; Cc1cc2c3c(c1)N(c1ccc(C(C)(C)C)cc1-c1ccccc1)c1cc4sc5ccccc5c4cc1B3N1c3ccccc3C(c3ccccc3)(c3ccccc3)c3cccc-2c31] 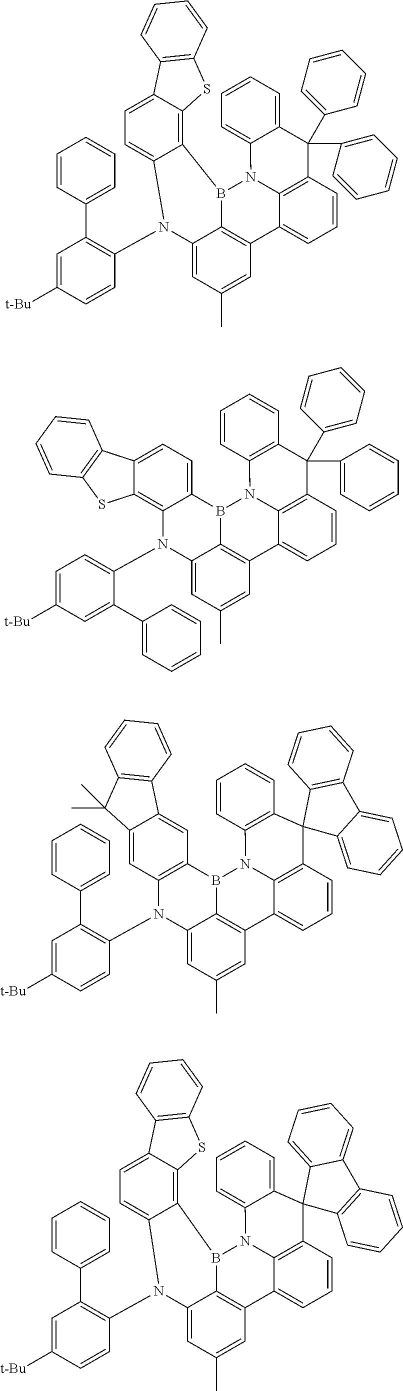 [SMILES: Cc1cc2c3c(c1)N(c1ccc(C(C)(C)C)cc1-c1ccccc1)c1ccc4c(sc5ccccc54)c1B3N1c3ccccc3C(c3ccccc3)(c3ccccc3)c3cccc-2c31 ; Cc1cc2c3c(c1)N(c1ccc(C(C)(C)C)cc1-c1ccccc1)c1c(ccc4c1sc1ccccc14)B3N1c3ccccc3C(c3ccccc3)(c3ccccc3)c3cccc-2c31 ; Cc1cc2c3c(c1)N(c1ccc(C(C)(C)C)cc1-c1ccccc1)c1cc4c(cc1B3N1c3ccccc3C3(c5ccccc5-c5ccccc53)c3cccc-2c31)-c1ccccc1C4(C)C ; Cc1cc2c3c(c1)N(c1ccc(C(C)(C)C)cc1-c1ccccc1)c1ccc4c(sc5ccccc54)c1B3N1c3ccccc3C3(c4ccccc4-c4ccccc43)c3cccc-2c31] 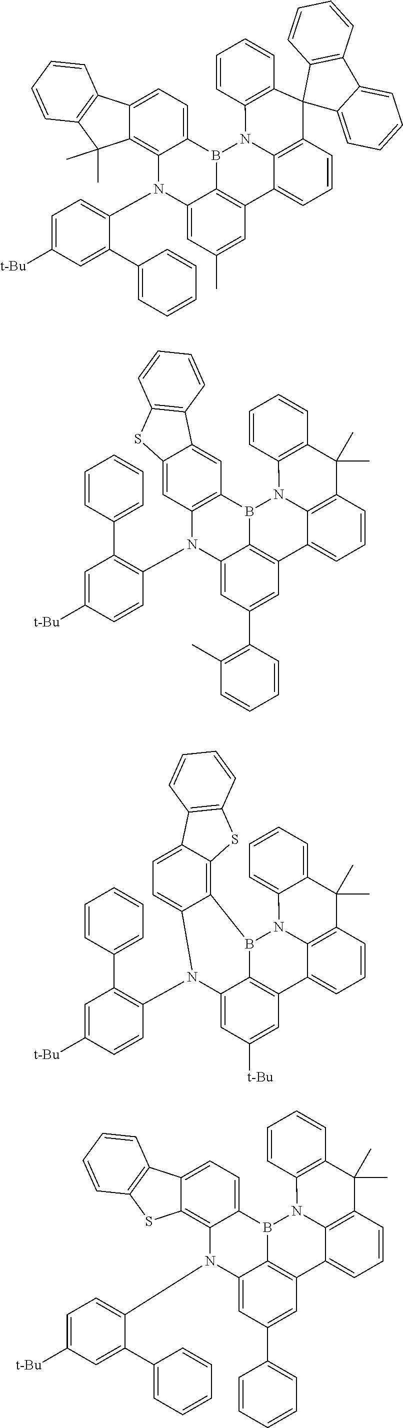 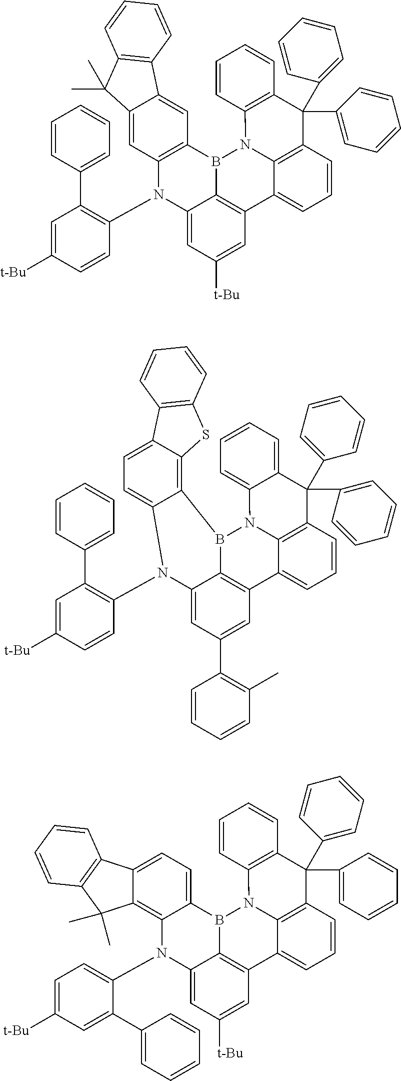 [SMILES: CC(C)(C)c1ccc(N2c3cc4c(cc3B3c5c(cc(C(C)(C)C)cc52)-c2cccc5c2N3c2ccccc2C5(c2ccccc2)c2ccccc2)-c2ccccc2C4(C)C)c(-c2ccccc2)c1 ; Cc1ccccc1-c1cc2c3c(c1)N(c1ccc(C(C)(C)C)cc1-c1ccccc1)c1ccc4c(sc5ccccc54)c1B3N1c3ccccc3C(c3ccccc3)(c3ccccc3)c3cccc-2c31 ; CC(C)(C)c1ccc(N2c3cc(C(C)(C)C)cc4c3B(c3ccc5c(c32)C(C)(C)c2ccccc2-5)N2c3ccccc3C(c3ccccc3)(c3ccccc3)c3cccc-4c32)c(-c2ccccc2)c1] 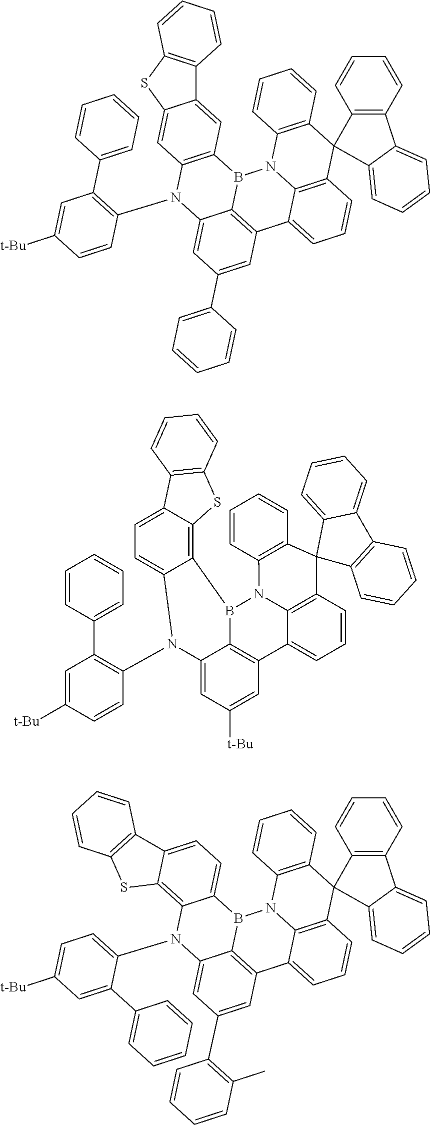 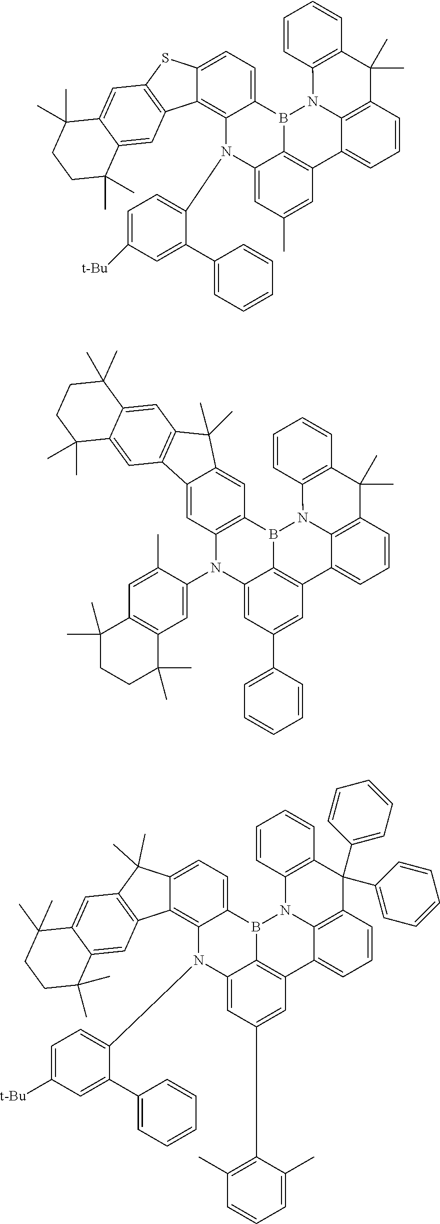 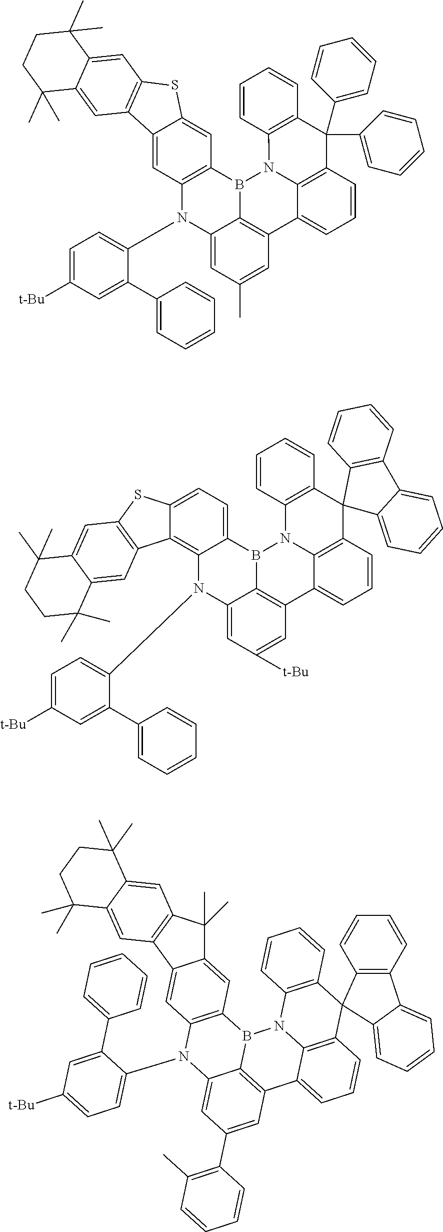 [SMILES: Cc1cc2c3c(c1)N(c1ccc(C(C)(C)C)cc1-c1ccccc1)c1cc4c(cc1B3N1c3ccccc3C(c3ccccc3)(c3ccccc3)c3cccc-2c31)sc1cc2c(cc14)C(C)(C)CCC2(C)C ; CC(C)(C)c1ccc(N2c3cc(C(C)(C)C)cc4c3B(c3ccc5sc6cc7c(cc6c5c32)C(C)(C)CCC7(C)C)N2c3ccccc3C3(c5ccccc5-c5ccccc53)c3cccc-4c32)c(-c2ccccc2)c1 ; Cc1ccccc1-c1cc2c3c(c1)N(c1ccc(C(C)(C)C)cc1-c1ccccc1)c1cc4c(cc1B3N1c3ccccc3C3(c5ccccc5-c5ccccc53)c3cccc-2c31)C(C)(C)c1cc2c(cc1-4)C(C)(C)CCC2(C)C] 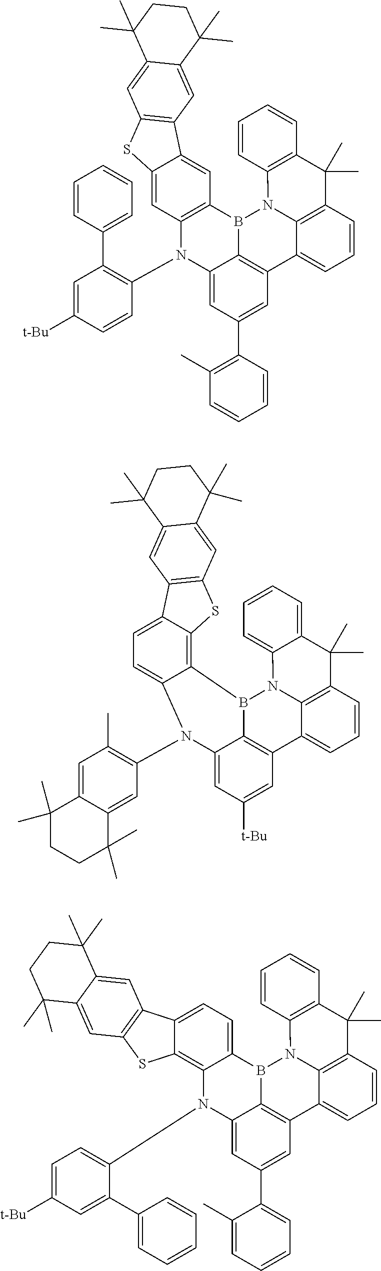 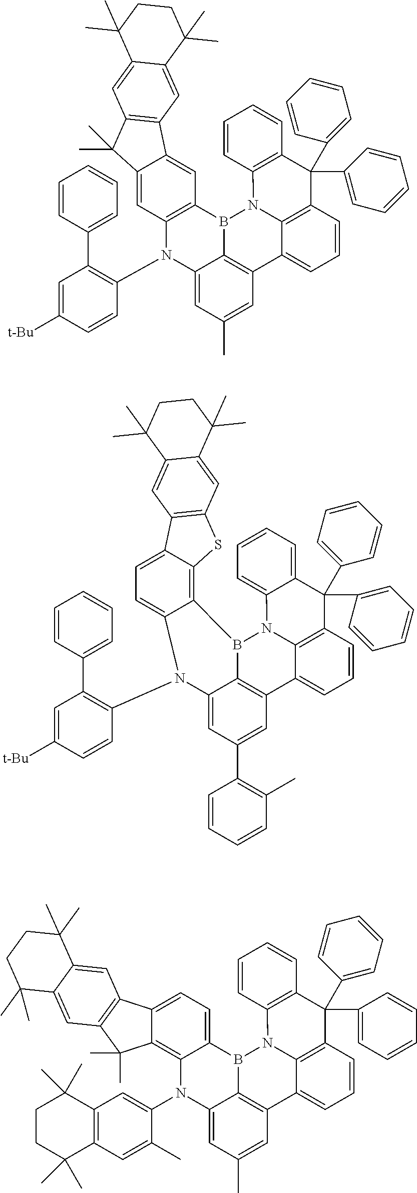 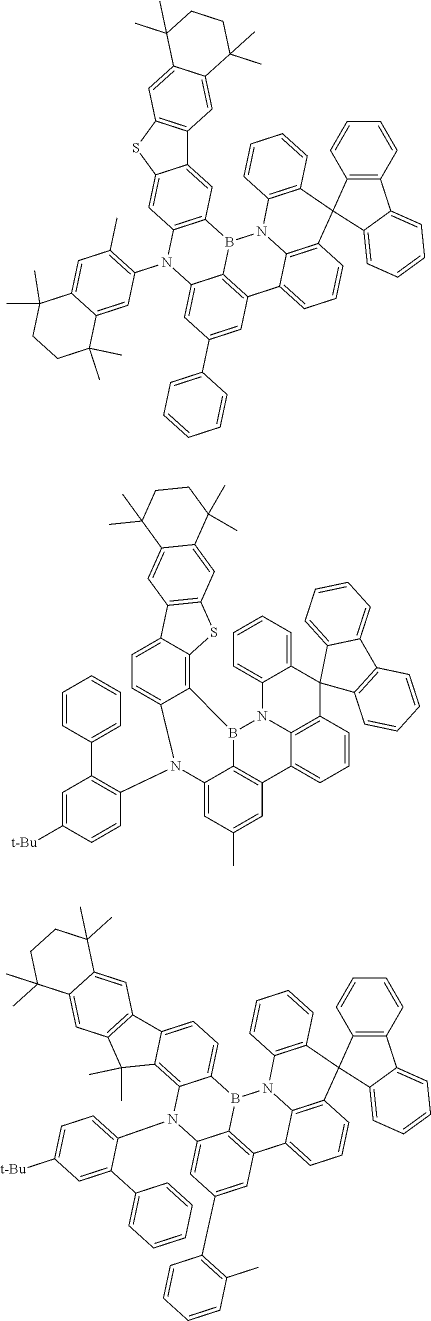 [SMILES: Cc1cc2c(cc1N1c3cc4sc5cc6c(cc5c4cc3B3c4c(cc(-c5ccccc5)cc41)-c1cccc4c1N3c1ccccc1C41c3ccccc3-c3ccccc31)C(C)(C)CCC6(C)C)C(C)(C)CCC2(C)C ; Cc1cc2c3c(c1)N(c1ccc(C(C)(C)C)cc1-c1ccccc1)c1ccc4c(sc5cc6c(cc54)C(C)(C)CCC6(C)C)c1B3N1c3ccccc3C3(c4ccccc4-c4ccccc43)c3cccc-2c31 ; Cc1ccccc1-c1cc2c3c(c1)N(c1ccc(C(C)(C)C)cc1-c1ccccc1)c1c(ccc4c1C(C)(C)c1cc5c(cc1-4)C(C)(C)CCC5(C)C)B3N1c3ccccc3C3(c4ccccc4-c4ccccc43)c3cccc-2c31] 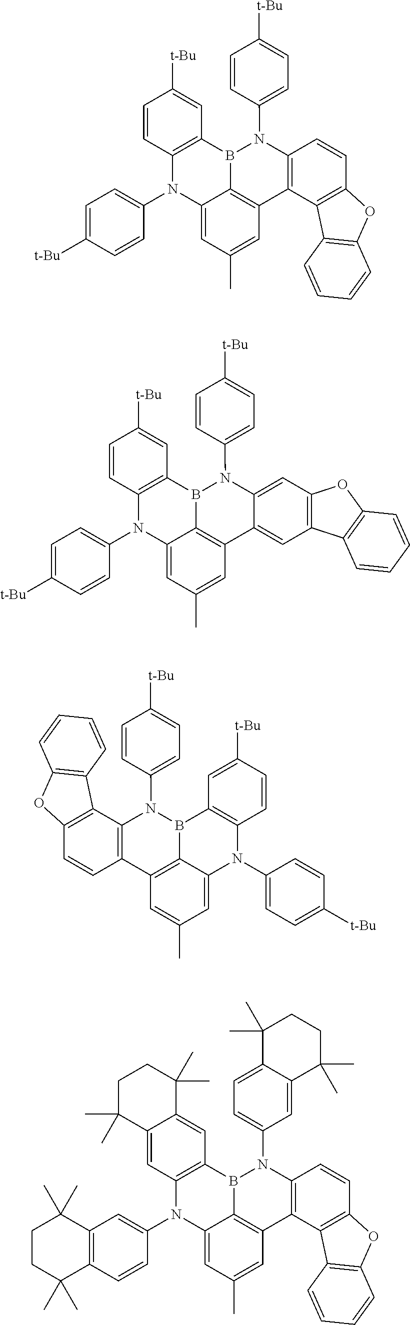 [SMILES: Cc1cc2c3c(c1)N(c1ccc(C(C)(C)C)cc1)c1ccc(C(C)(C)C)cc1B3N(c1ccc(C(C)(C)C)cc1)c1ccc3oc4ccccc4c3c1-2 ; Cc1cc2c3c(c1)N(c1ccc(C(C)(C)C)cc1)c1ccc(C(C)(C)C)cc1B3N(c1ccc(C(C)(C)C)cc1)c1cc3oc4ccccc4c3cc1-2 ; Cc1cc2c3c(c1)N(c1ccc(C(C)(C)C)cc1)c1ccc(C(C)(C)C)cc1B3N(c1ccc(C(C)(C)C)cc1)c1c-2ccc2oc3ccccc3c12 ; Cc1cc2c3c(c1)N(c1ccc4c(c1)C(C)(C)CCC4(C)C)c1cc4c(cc1B3N(c1ccc3c(c1)C(C)(C)CCC3(C)C)c1ccc3oc5ccccc5c3c1-2)C(C)(C)CCC4(C)C] 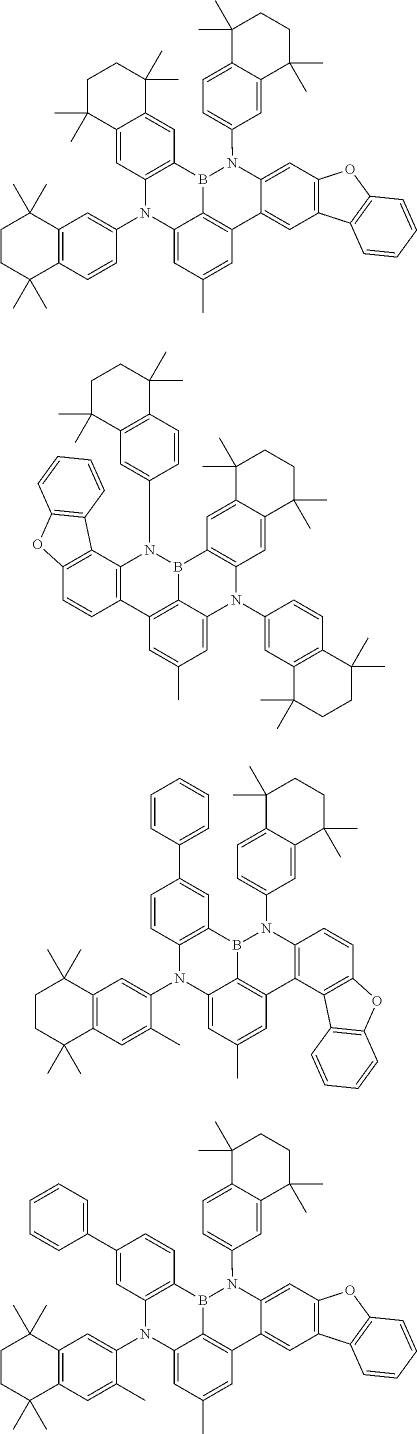 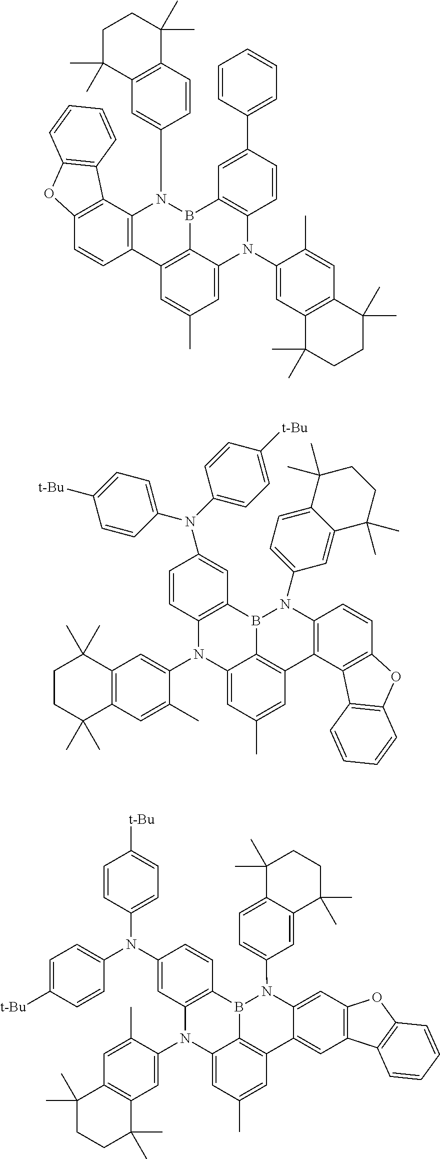 [SMILES: Cc1cc2c3c(c1)N(c1cc4c(cc1C)C(C)(C)CCC4(C)C)c1ccc(-c4ccccc4)cc1B3N(c1ccc3c(c1)C(C)(C)CCC3(C)C)c1c-2ccc2oc3ccccc3c12 ; Cc1cc2c3c(c1)N(c1cc4c(cc1C)C(C)(C)CCC4(C)C)c1ccc(N(c4ccc(C(C)(C)C)cc4)c4ccc(C(C)(C)C)cc4)cc1B3N(c1ccc3c(c1)C(C)(C)CCC3(C)C)c1ccc3oc4ccccc4c3c1-2 ; Cc1cc2c3c(c1)N(c1cc4c(cc1C)C(C)(C)CCC4(C)C)c1cc(N(c4ccc(C(C)(C)C)cc4)c4ccc(C(C)(C)C)cc4)ccc1B3N(c1ccc3c(c1)C(C)(C)CCC3(C)C)c1cc3oc4ccccc4c3cc1-2] 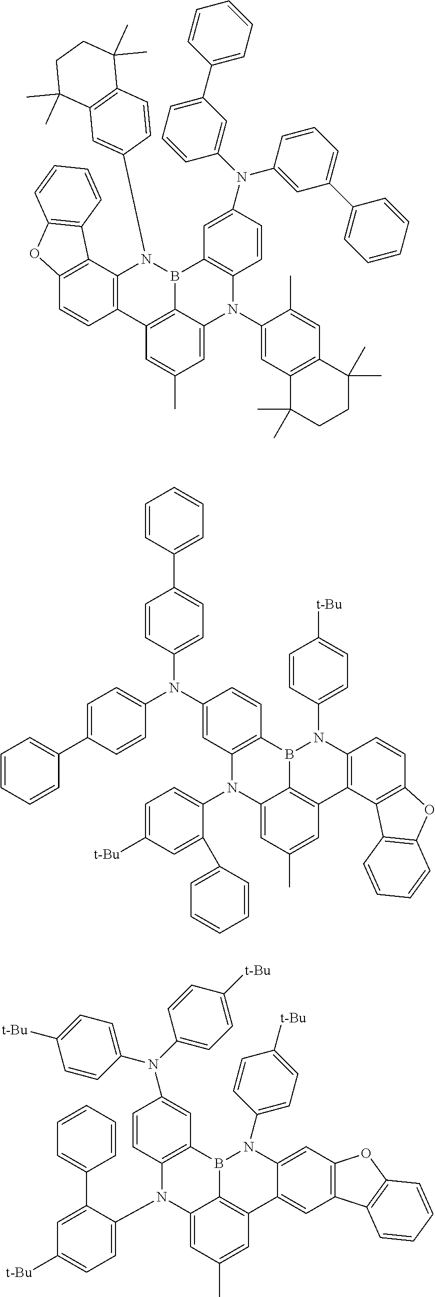 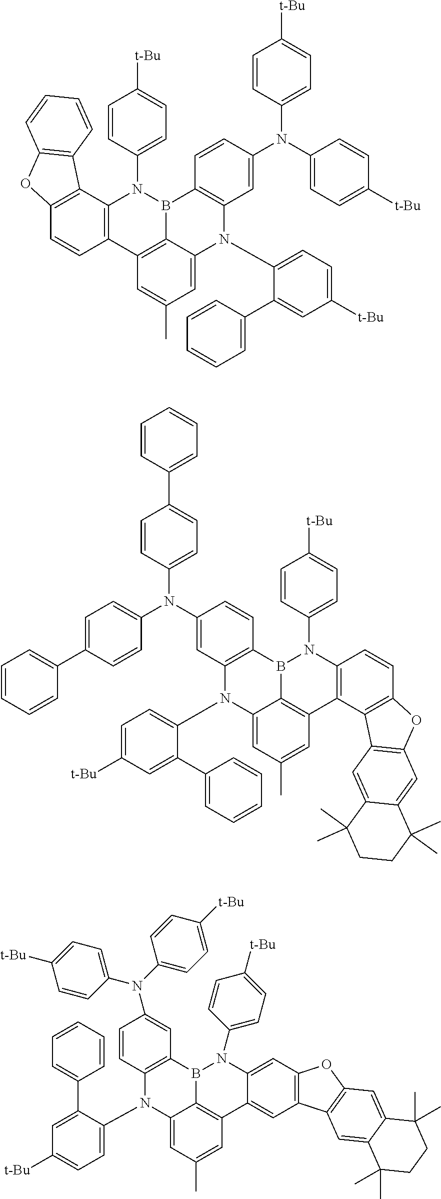 [SMILES: Cc1cc2c3c(c1)N(c1ccc(C(C)(C)C)cc1-c1ccccc1)c1cc(N(c4ccc(C(C)(C)C)cc4)c4ccc(C(C)(C)C)cc4)ccc1B3N(c1ccc(C(C)(C)C)cc1)c1c-2ccc2oc3ccccc3c12 ; Cc1cc2c3c(c1)N(c1ccc(C(C)(C)C)cc1-c1ccccc1)c1cc(N(c4ccc(-c5ccccc5)cc4)c4ccc(-c5ccccc5)cc4)ccc1B3N(c1ccc(C(C)(C)C)cc1)c1ccc3oc4cc5c(cc4c3c1-2)C(C)(C)CCC5(C)C ; Cc1cc2c3c(c1)N(c1ccc(C(C)(C)C)cc1-c1ccccc1)c1ccc(N(c4ccc(C(C)(C)C)cc4)c4ccc(C(C)(C)C)cc4)cc1B3N(c1ccc(C(C)(C)C)cc1)c1cc3oc4cc5c(cc4c3cc1-2)C(C)(C)CCC5(C)C] 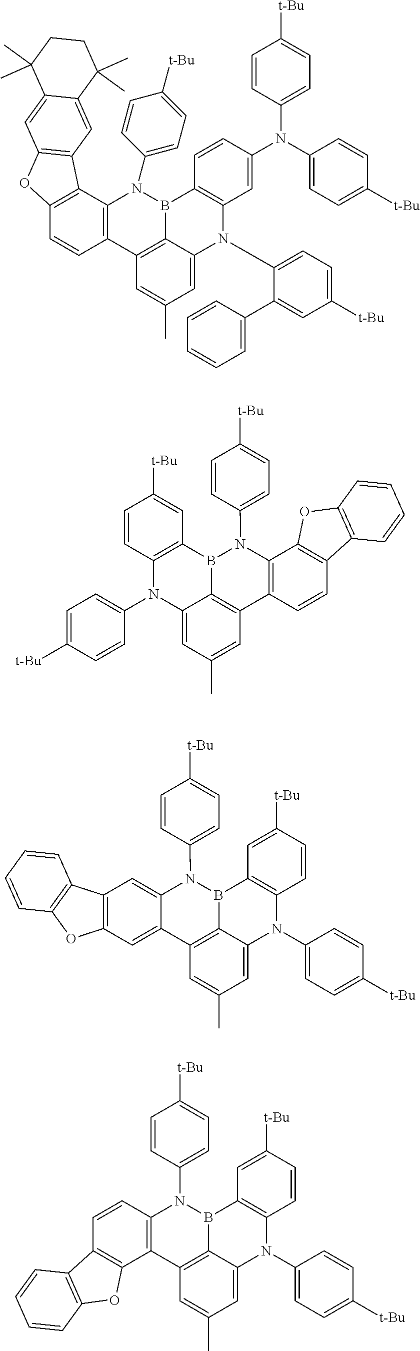 [SMILES: Cc1cc2c3c(c1)N(c1ccc(C(C)(C)C)cc1-c1ccccc1)c1cc(N(c4ccc(C(C)(C)C)cc4)c4ccc(C(C)(C)C)cc4)ccc1B3N(c1ccc(C(C)(C)C)cc1)c1c-2ccc2oc3cc4c(cc3c12)C(C)(C)CCC4(C)C ; Cc1cc2c3c(c1)N(c1ccc(C(C)(C)C)cc1)c1ccc(C(C)(C)C)cc1B3N(c1ccc(C(C)(C)C)cc1)c1c-2ccc2c1oc1ccccc12 ; Cc1cc2c3c(c1)N(c1ccc(C(C)(C)C)cc1)c1ccc(C(C)(C)C)cc1B3N(c1ccc(C(C)(C)C)cc1)c1cc3c(cc1-2)oc1ccccc13 ; Cc1cc2c3c(c1)N(c1ccc(C(C)(C)C)cc1)c1ccc(C(C)(C)C)cc1B3N(c1ccc(C(C)(C)C)cc1)c1ccc3c(oc4ccccc43)c1-2] 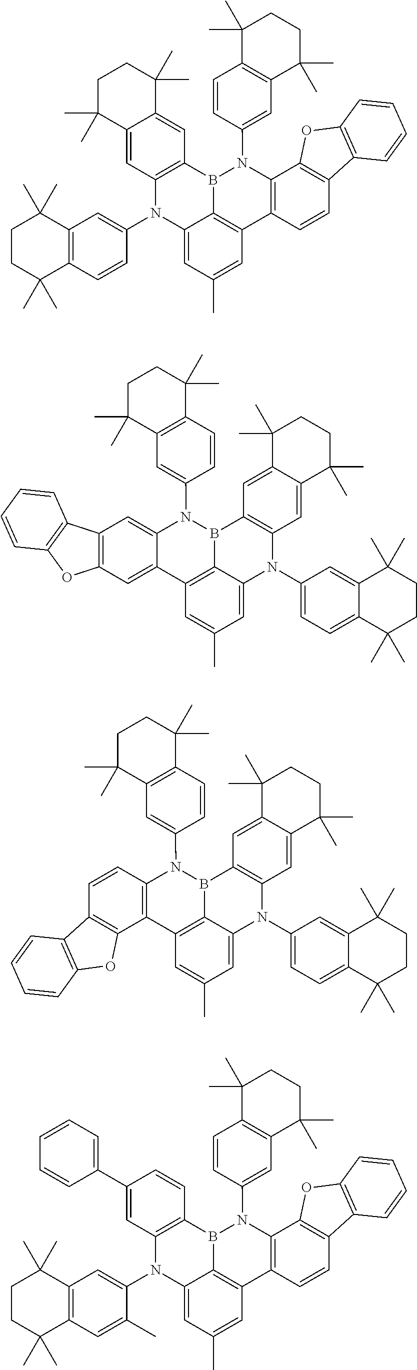 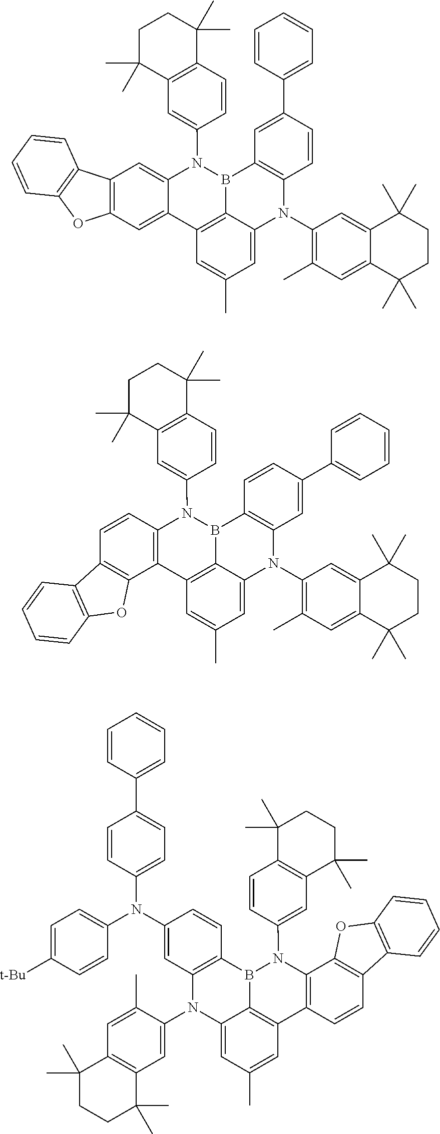 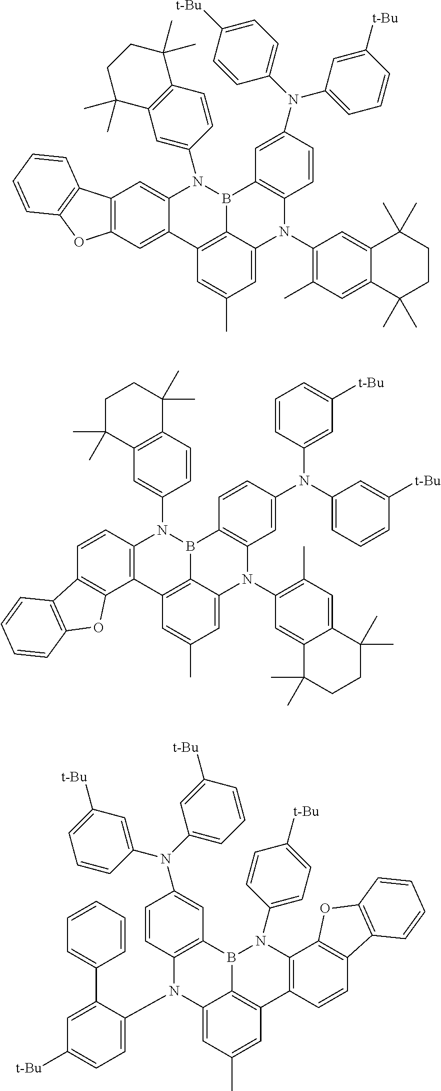 [SMILES: Cc1cc2c3c(c1)N(c1cc4c(cc1C)C(C)(C)CCC4(C)C)c1ccc(N(c4ccc(C(C)(C)C)cc4)c4cccc(C(C)(C)C)c4)cc1B3N(c1ccc3c(c1)C(C)(C)CCC3(C)C)c1cc3c(cc1-2)oc1ccccc13 ; Cc1cc2c3c(c1)N(c1cc4c(cc1C)C(C)(C)CCC4(C)C)c1cc(N(c4cccc(C(C)(C)C)c4)c4cccc(C(C)(C)C)c4)ccc1B3N(c1ccc3c(c1)C(C)(C)CCC3(C)C)c1ccc3c(oc4ccccc43)c1-2 ; Cc1cc2c3c(c1)N(c1ccc(C(C)(C)C)cc1-c1ccccc1)c1ccc(N(c4cccc(C(C)(C)C)c4)c4cccc(C(C)(C)C)c4)cc1B3N(c1ccc(C(C)(C)C)cc1)c1c-2ccc2c1oc1ccccc12] 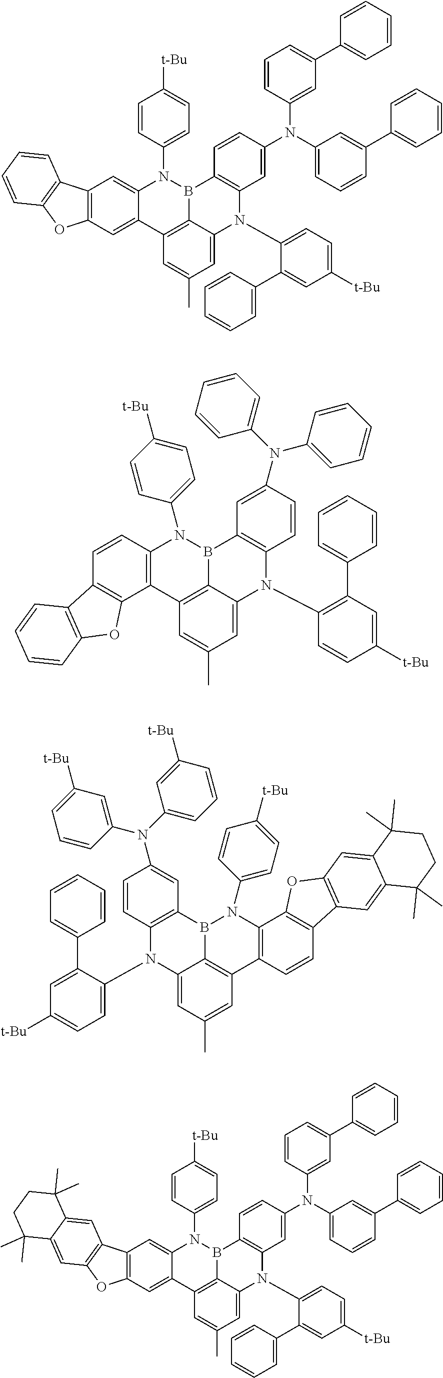 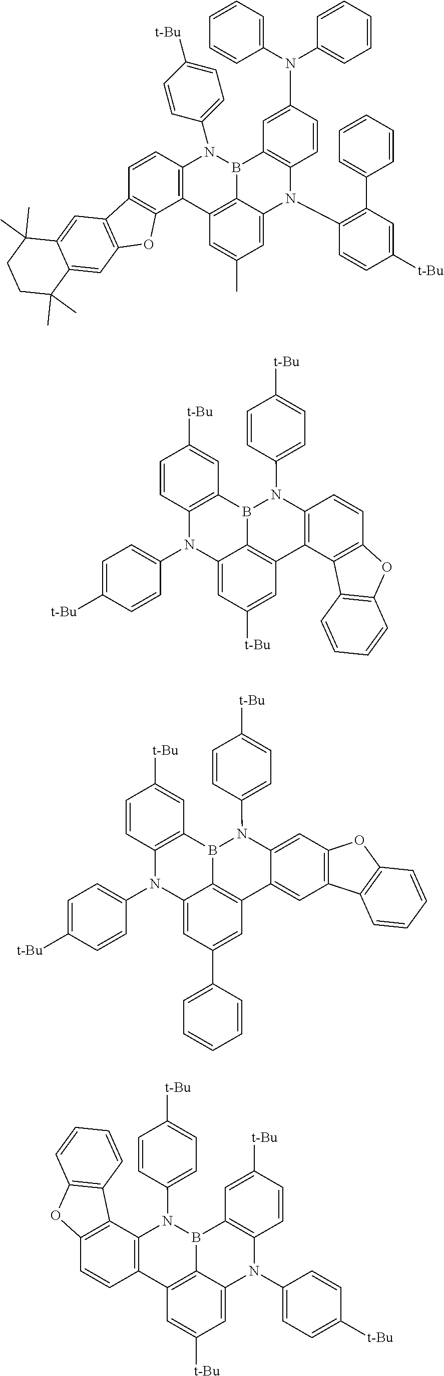 [SMILES: Cc1cc2c3c(c1)N(c1ccc(C(C)(C)C)cc1-c1ccccc1)c1ccc(N(c4ccccc4)c4ccccc4)cc1B3N(c1ccc(C(C)(C)C)cc1)c1ccc3c(oc4cc5c(cc43)C(C)(C)CCC5(C)C)c1-2 ; CC(C)(C)c1ccc(N2B3c4cc(C(C)(C)C)ccc4N(c4ccc(C(C)(C)C)cc4)c4cc(C(C)(C)C)cc(c43)-c3c2ccc2oc4ccccc4c32)cc1 ; CC(C)(C)c1ccc(N2B3c4cc(C(C)(C)C)ccc4N(c4ccc(C(C)(C)C)cc4)c4cc(-c5ccccc5)cc(c43)-c3cc4c(cc32)oc2ccccc24)cc1 ; CC(C)(C)c1ccc(N2B3c4cc(C(C)(C)C)ccc4N(c4ccc(C(C)(C)C)cc4)c4cc(C(C)(C)C)cc(c43)-c3ccc4oc5ccccc5c4c32)cc1] 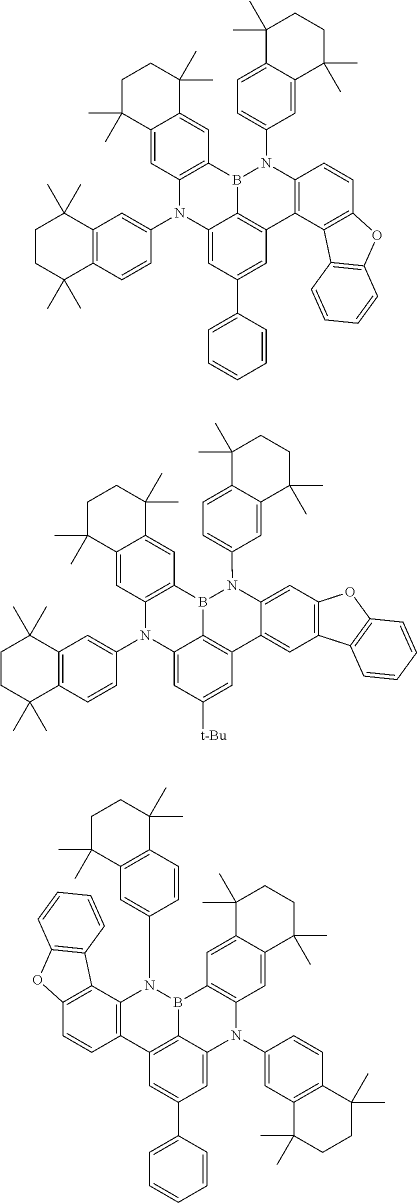 [SMILES: CC1(C)CCC(C)(C)c2cc(N3B4c5cc6c(cc5N(c5ccc7c(c5)C(C)(C)CCC7(C)C)c5cc(-c7ccccc7)cc(c54)-c4c3ccc3oc5ccccc5c43)C(C)(C)CCC6(C)C)ccc21 ; CC(C)(C)c1cc2c3c(c1)N(c1ccc4c(c1)C(C)(C)CCC4(C)C)c1cc4c(cc1B3N(c1ccc3c(c1)C(C)(C)CCC3(C)C)c1cc3oc5ccccc5c3cc1-2)C(C)(C)CCC4(C)C ; CC1(C)CCC(C)(C)c2cc(N3B4c5cc6c(cc5N(c5ccc7c(c5)C(C)(C)CCC7(C)C)c5cc(-c7ccccc7)cc(c54)-c4ccc5oc7ccccc7c5c43)C(C)(C)CCC6(C)C)ccc21] 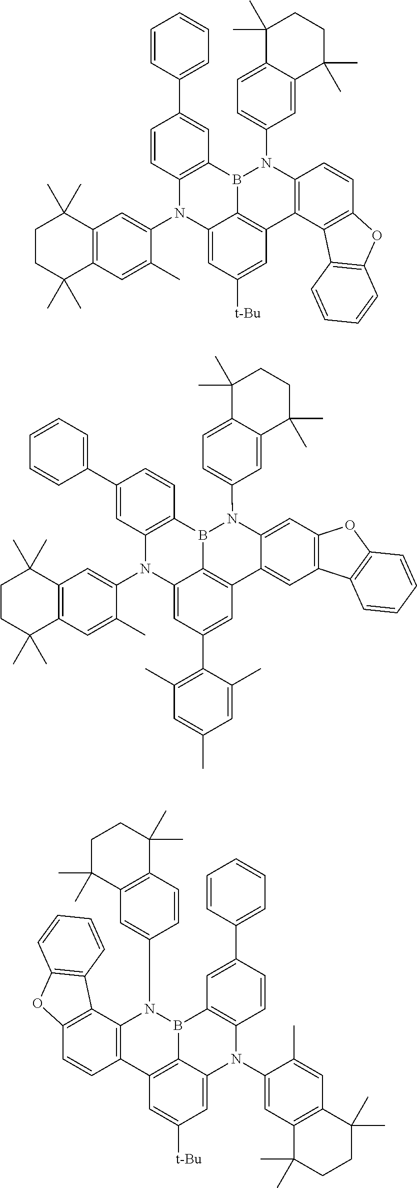 [SMILES: Cc1cc2c(cc1N1c3ccc(-c4ccccc4)cc3B3c4c(cc(C(C)(C)C)cc41)-c1c(ccc4oc5ccccc5c14)N3c1ccc3c(c1)C(C)(C)CCC3(C)C)C(C)(C)CCC2(C)C ; Cc1cc(C)c(-c2cc3c4c(c2)N(c2cc5c(cc2C)C(C)(C)CCC5(C)C)c2cc(-c5ccccc5)ccc2B4N(c2ccc4c(c2)C(C)(C)CCC4(C)C)c2cc4oc5ccccc5c4cc2-3)c(C)c1 ; Cc1cc2c(cc1N1c3ccc(-c4ccccc4)cc3B3c4c(cc(C(C)(C)C)cc41)-c1ccc4oc5ccccc5c4c1N3c1ccc3c(c1)C(C)(C)CCC3(C)C)C(C)(C)CCC2(C)C] 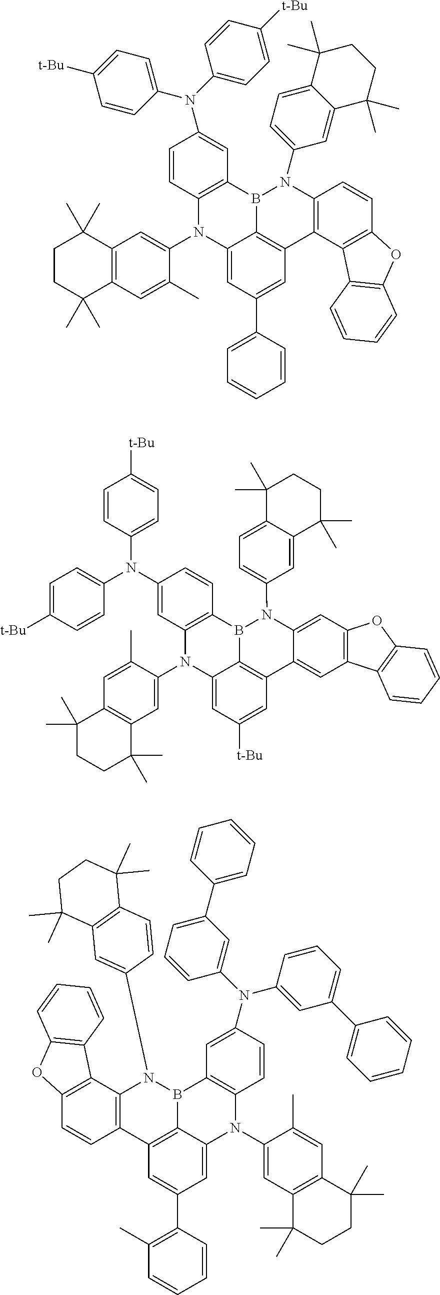 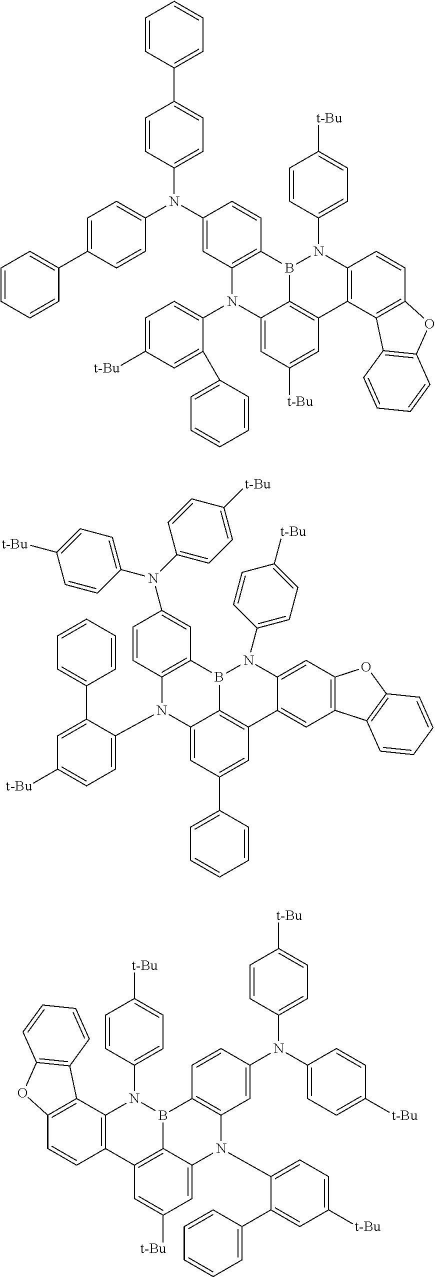 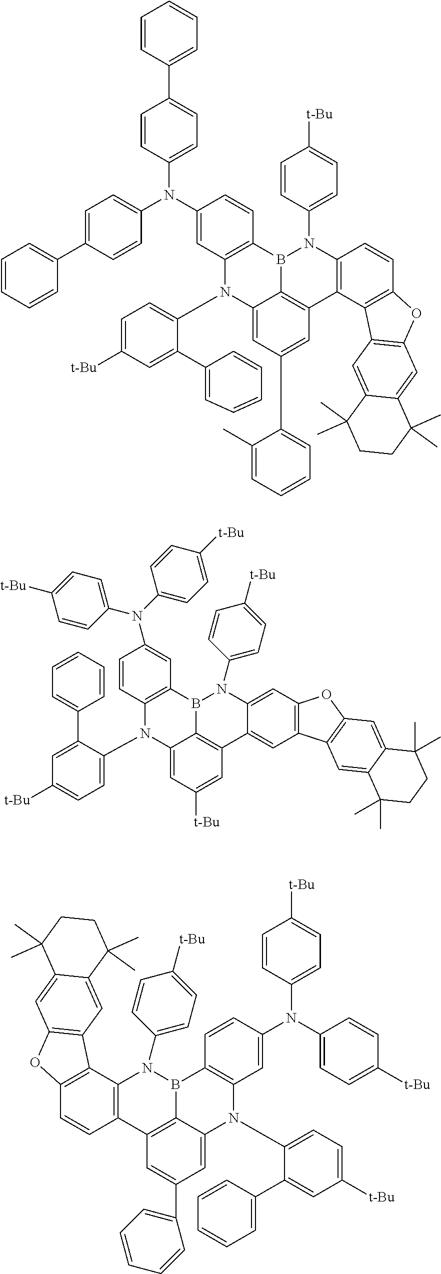 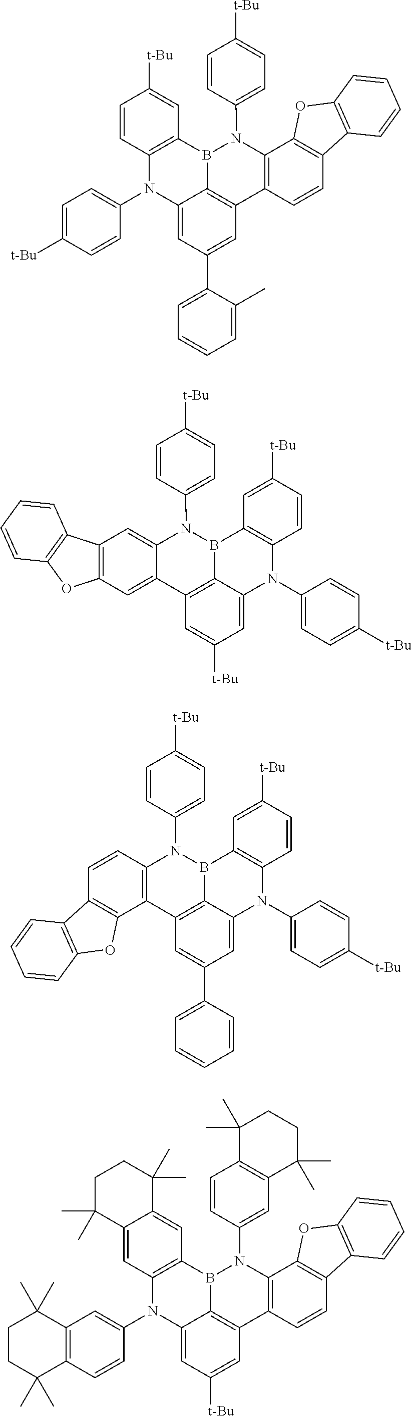 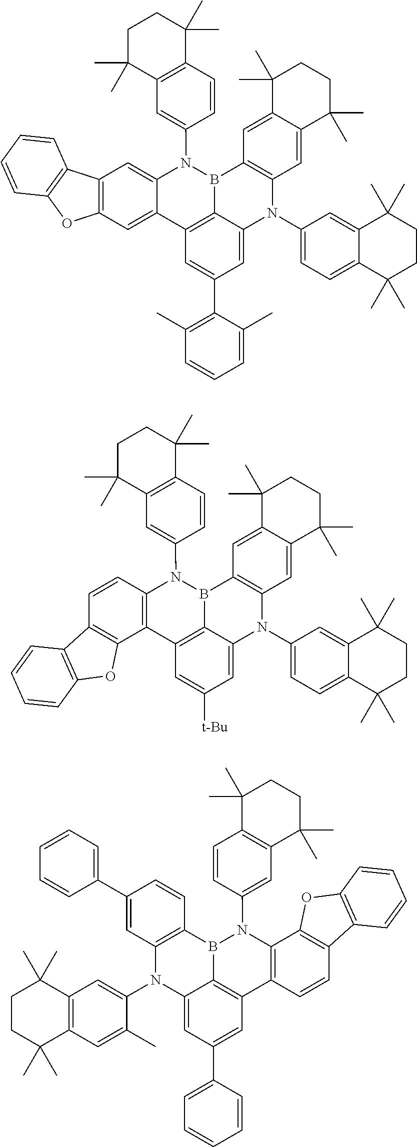 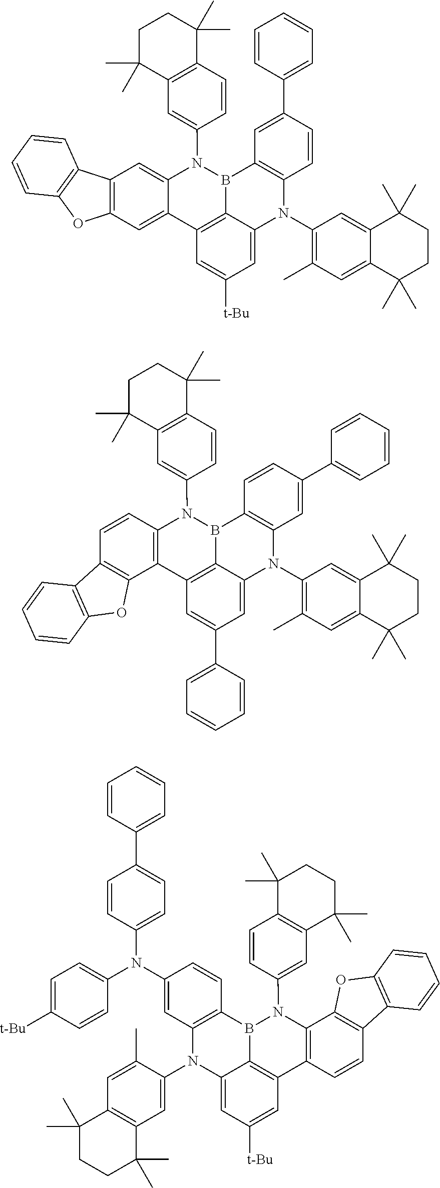 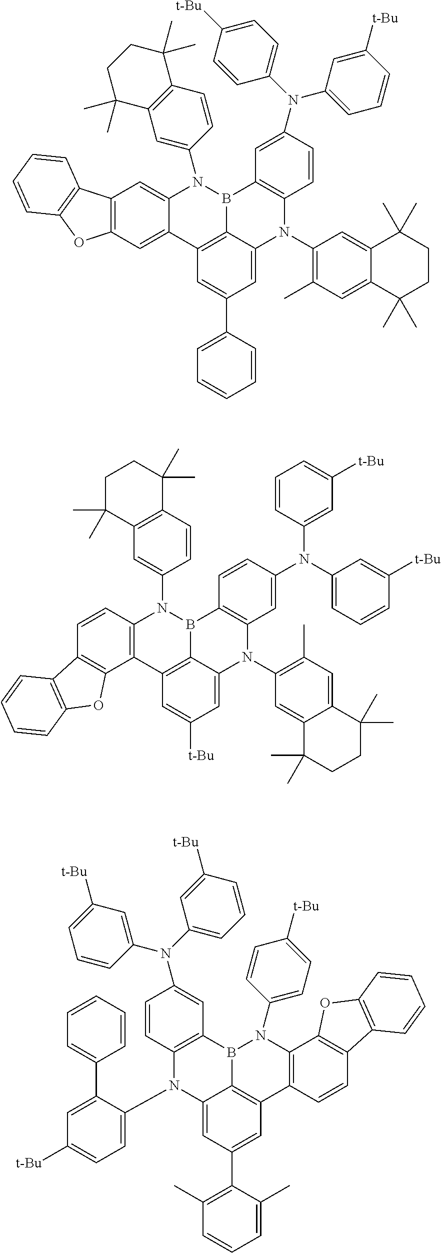 [SMILES: Cc1cc2c(cc1N1c3ccc(N(c4ccc(C(C)(C)C)cc4)c4cccc(C(C)(C)C)c4)cc3B3c4c(cc(-c5ccccc5)cc41)-c1cc4oc5ccccc5c4cc1N3c1ccc3c(c1)C(C)(C)CCC3(C)C)C(C)(C)CCC2(C)C ; Cc1cc2c(cc1N1c3cc(N(c4cccc(C(C)(C)C)c4)c4cccc(C(C)(C)C)c4)ccc3B3c4c(cc(C(C)(C)C)cc41)-c1c(ccc4c1oc1ccccc14)N3c1ccc3c(c1)C(C)(C)CCC3(C)C)C(C)(C)CCC2(C)C ; Cc1cccc(C)c1-c1cc2c3c(c1)N(c1ccc(C(C)(C)C)cc1-c1ccccc1)c1ccc(N(c4cccc(C(C)(C)C)c4)c4cccc(C(C)(C)C)c4)cc1B3N(c1ccc(C(C)(C)C)cc1)c1c-2ccc2c1oc1ccccc12] 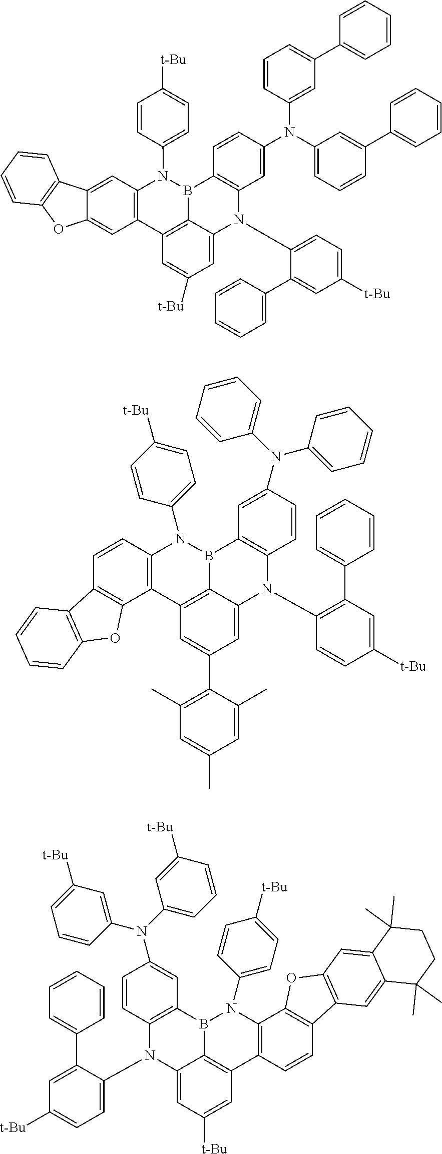 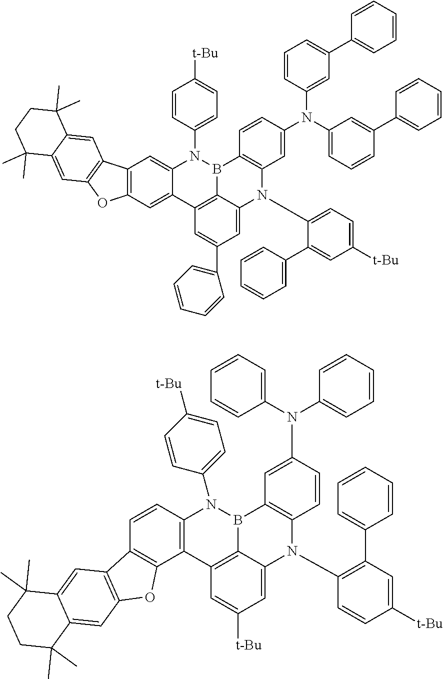 [SMILES: CC(C)(C)c1ccc(N2B3c4ccc(N(c5cccc(-c6ccccc6)c5)c5cccc(-c6ccccc6)c5)cc4N(c4ccc(C(C)(C)C)cc4-c4ccccc4)c4cc(-c5ccccc5)cc(c43)-c3cc4oc5cc6c(cc5c4cc32)C(C)(C)CCC6(C)C)cc1 ; CC(C)(C)c1ccc(N2B3c4cc(N(c5ccccc5)c5ccccc5)ccc4N(c4ccc(C(C)(C)C)cc4-c4ccccc4)c4cc(C(C)(C)C)cc(c43)-c3c2ccc2c3oc3cc4c(cc32)C(C)(C)CCC4(C)C)cc1] 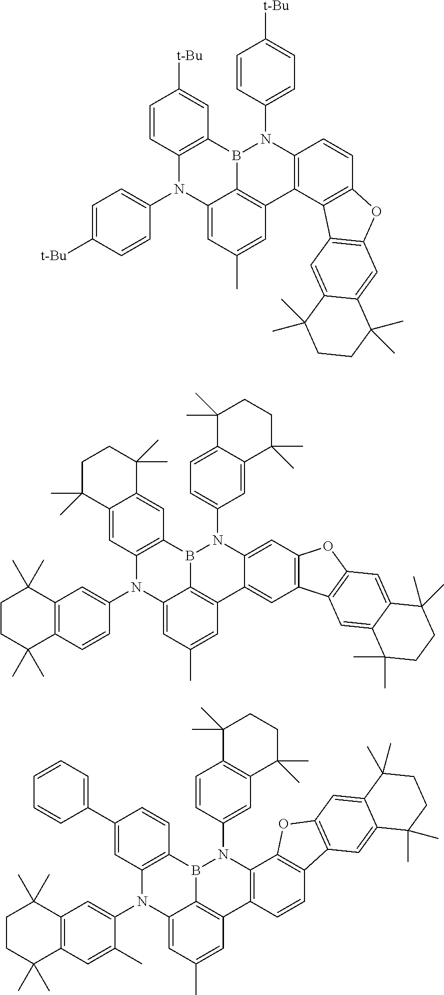 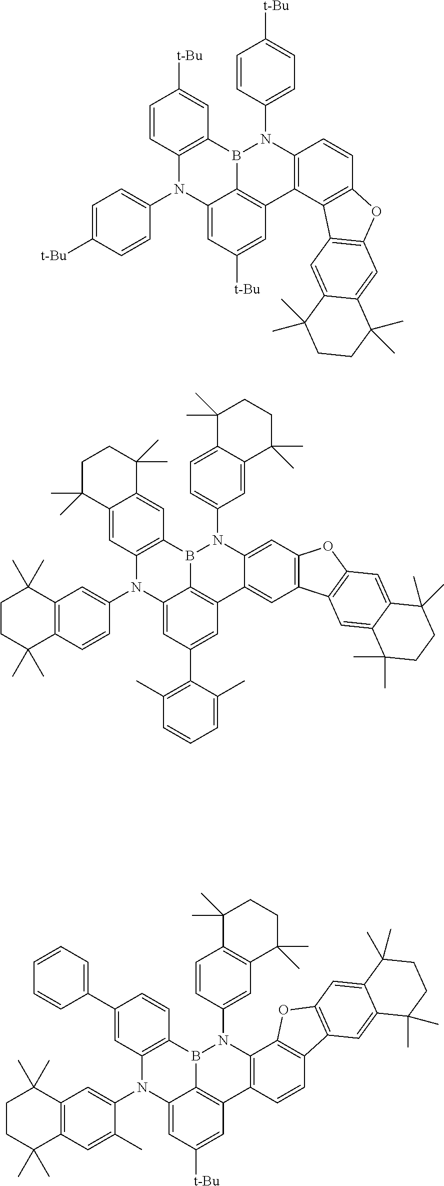 [SMILES: CC(C)(C)c1ccc(N2B3c4cc(C(C)(C)C)ccc4N(c4ccc(C(C)(C)C)cc4)c4cc(C(C)(C)C)cc(c43)-c3c2ccc2oc4cc5c(cc4c32)C(C)(C)CCC5(C)C)cc1 ; Cc1cccc(C)c1-c1cc2c3c(c1)N(c1ccc4c(c1)C(C)(C)CCC4(C)C)c1cc4c(cc1B3N(c1ccc3c(c1)C(C)(C)CCC3(C)C)c1cc3oc5cc6c(cc5c3cc1-2)C(C)(C)CCC6(C)C)C(C)(C)CCC4(C)C ; Cc1cc2c(cc1N1c3cc(-c4ccccc4)ccc3B3c4c(cc(C(C)(C)C)cc41)-c1ccc4c(oc5cc6c(cc54)C(C)(C)CCC6(C)C)c1N3c1ccc3c(c1)C(C)(C)CCC3(C)C)C(C)(C)CCC2(C)C] 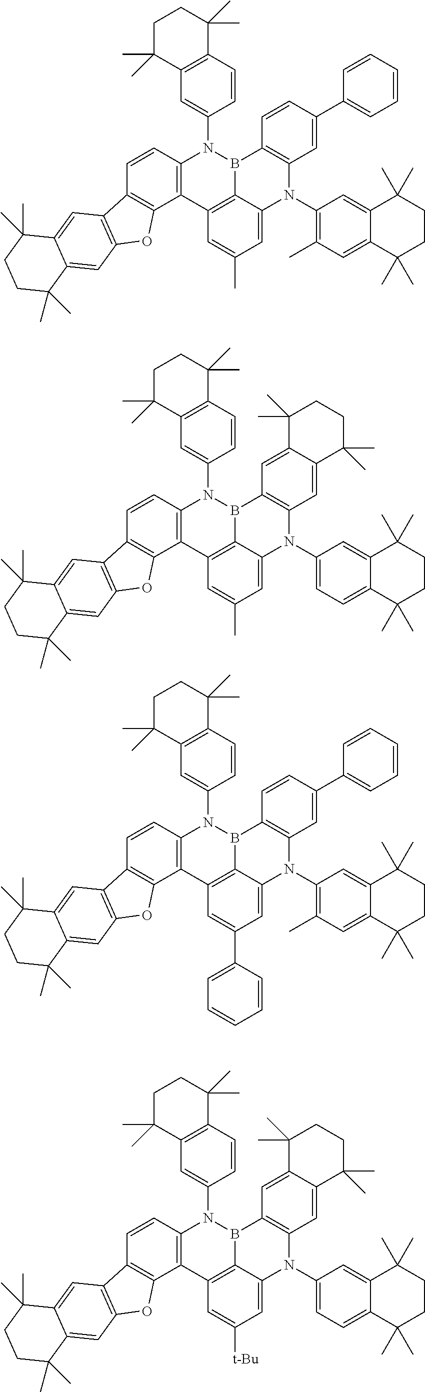 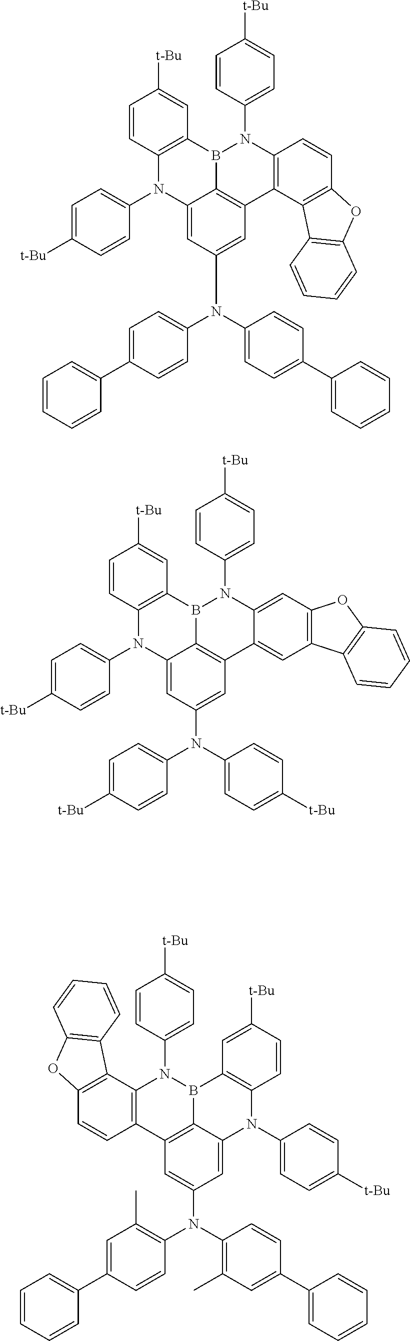 [SMILES: CC(C)(C)c1ccc(N2B3c4cc(C(C)(C)C)ccc4N(c4ccc(C(C)(C)C)cc4)c4cc(N(c5ccc(-c6ccccc6)cc5)c5ccc(-c6ccccc6)cc5)cc(c43)-c3c2ccc2oc4ccccc4c32)cc1 ; CC(C)(C)c1ccc(N2B3c4cc(C(C)(C)C)ccc4N(c4ccc(C(C)(C)C)cc4)c4cc(N(c5ccc(C(C)(C)C)cc5)c5ccc(C(C)(C)C)cc5)cc(c43)-c3cc4c(cc32)oc2ccccc24)cc1 ; Cc1cc(-c2ccccc2)ccc1N(c1cc2c3c(c1)N(c1ccc(C(C)(C)C)cc1)c1ccc(C(C)(C)C)cc1B3N(c1ccc(C(C)(C)C)cc1)c1c-2ccc2oc3ccccc3c12)c1ccc(-c2ccccc2)cc1C] 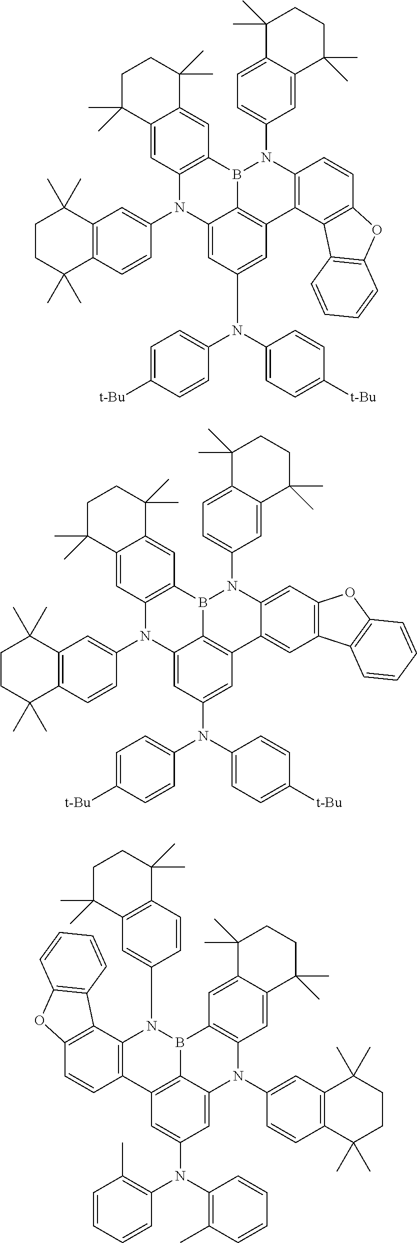 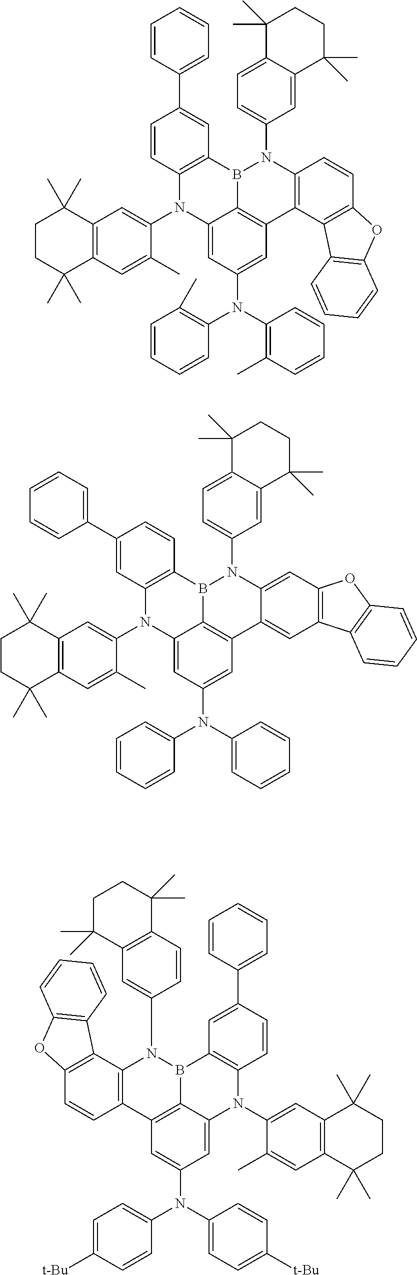 [SMILES: Cc1ccccc1N(c1cc2c3c(c1)N(c1cc4c(cc1C)C(C)(C)CCC4(C)C)c1ccc(-c4ccccc4)cc1B3N(c1ccc3c(c1)C(C)(C)CCC3(C)C)c1ccc3oc4ccccc4c3c1-2)c1ccccc1C ; Cc1cc2c(cc1N1c3cc(-c4ccccc4)ccc3B3c4c(cc(N(c5ccccc5)c5ccccc5)cc41)-c1cc4c(cc1N3c1ccc3c(c1)C(C)(C)CCC3(C)C)oc1ccccc14)C(C)(C)CCC2(C)C ; Cc1cc2c(cc1N1c3ccc(-c4ccccc4)cc3B3c4c(cc(N(c5ccc(C(C)(C)C)cc5)c5ccc(C(C)(C)C)cc5)cc41)-c1ccc4oc5ccccc5c4c1N3c1ccc3c(c1)C(C)(C)CCC3(C)C)C(C)(C)CCC2(C)C] 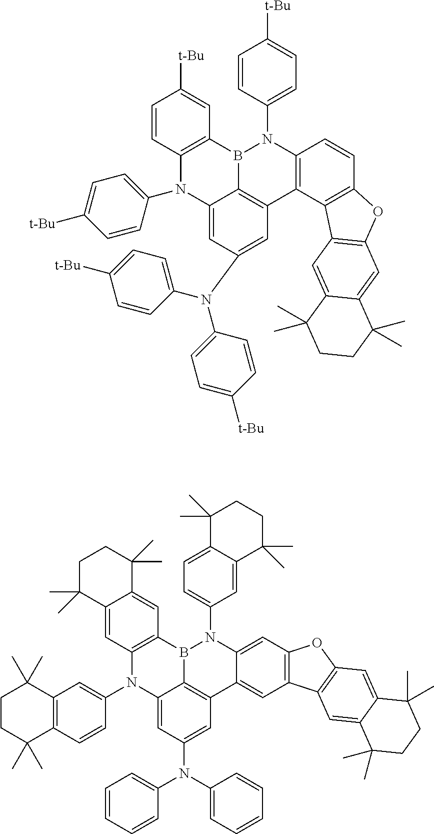 [SMILES: CC(C)(C)c1ccc(N2B3c4cc(C(C)(C)C)ccc4N(c4ccc(C(C)(C)C)cc4)c4cc(N(c5ccc(C(C)(C)C)cc5)c5ccc(C(C)(C)C)cc5)cc(c43)-c3c2ccc2oc4cc5c(cc4c32)C(C)(C)CCC5(C)C)cc1 ; CC1(C)CCC(C)(C)c2cc(N3B4c5cc6c(cc5N(c5ccc7c(c5)C(C)(C)CCC7(C)C)c5cc(N(c7ccccc7)c7ccccc7)cc(c54)-c4cc5c(cc43)oc3cc4c(cc35)C(C)(C)CCC4(C)C)C(C)(C)CCC6(C)C)ccc21] 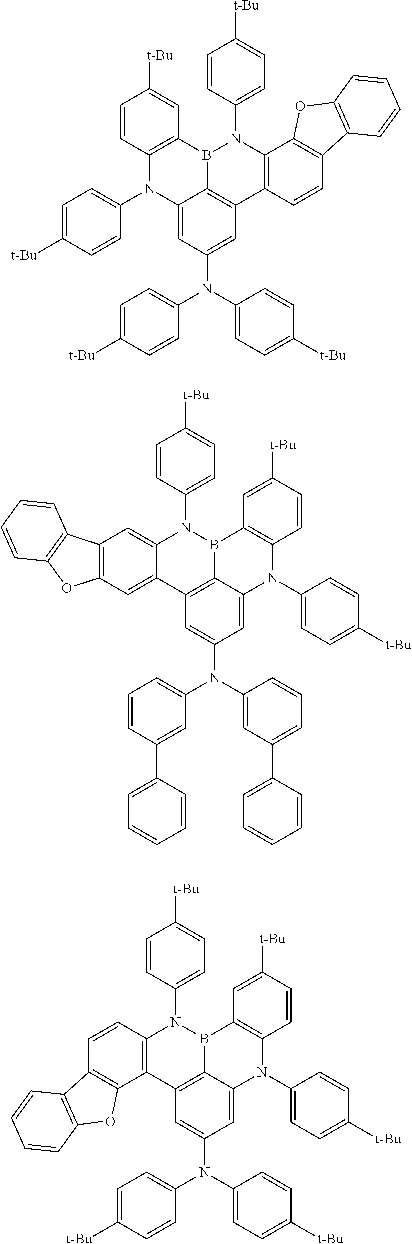 [SMILES: CC(C)(C)c1ccc(N2B3c4cc(C(C)(C)C)ccc4N(c4ccc(C(C)(C)C)cc4)c4cc(N(c5ccc(C(C)(C)C)cc5)c5ccc(C(C)(C)C)cc5)cc(c43)-c3ccc4c(oc5ccccc54)c32)cc1 ; CC(C)(C)c1ccc(N2B3c4cc(C(C)(C)C)ccc4N(c4ccc(C(C)(C)C)cc4)c4cc(N(c5cccc(-c6ccccc6)c5)c5cccc(-c6ccccc6)c5)cc(c43)-c3cc4oc5ccccc5c4cc32)cc1 ; CC(C)(C)c1ccc(N2B3c4cc(C(C)(C)C)ccc4N(c4ccc(C(C)(C)C)cc4)c4cc(N(c5ccc(C(C)(C)C)cc5)c5ccc(C(C)(C)C)cc5)cc(c43)-c3c2ccc2c3oc3ccccc32)cc1] 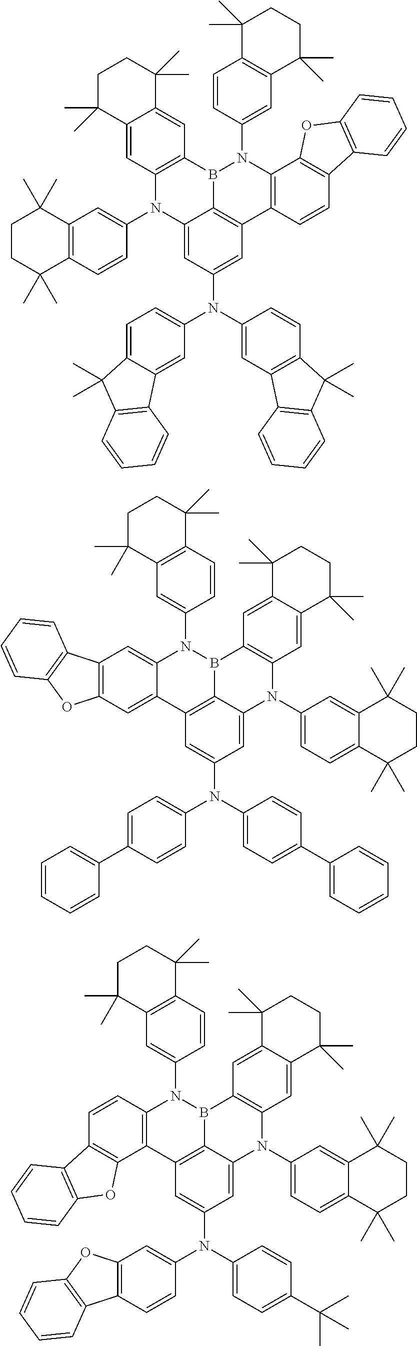 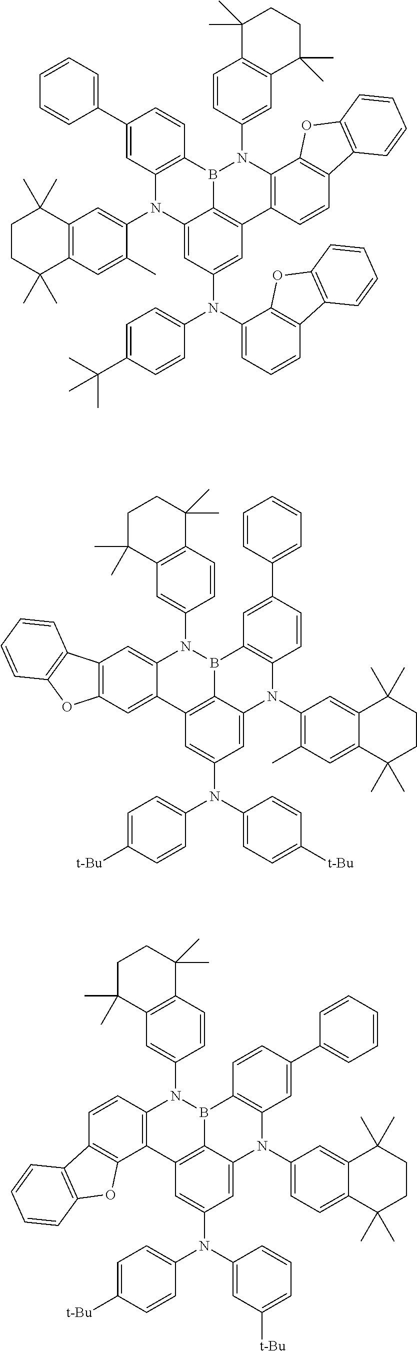 [SMILES: Cc1cc2c(cc1N1c3cc(-c4ccccc4)ccc3B3c4c(cc(N(c5ccc(C(C)(C)C)cc5)c5cccc6c5oc5ccccc56)cc41)-c1ccc4c(oc5ccccc54)c1N3c1ccc3c(c1)C(C)(C)CCC3(C)C)C(C)(C)CCC2(C)C ; Cc1cc2c(cc1N1c3ccc(-c4ccccc4)cc3B3c4c(cc(N(c5ccc(C(C)(C)C)cc5)c5ccc(C(C)(C)C)cc5)cc41)-c1cc4oc5ccccc5c4cc1N3c1ccc3c(c1)C(C)(C)CCC3(C)C)C(C)(C)CCC2(C)C ; CC(C)(C)c1ccc(N(c2cccc(C(C)(C)C)c2)c2cc3c4c(c2)N(c2ccc5c(c2)C(C)(C)CCC5(C)C)c2cc(-c5ccccc5)ccc2B4N(c2ccc4c(c2)C(C)(C)CCC4(C)C)c2ccc4c(oc5ccccc54)c2-3)cc1] 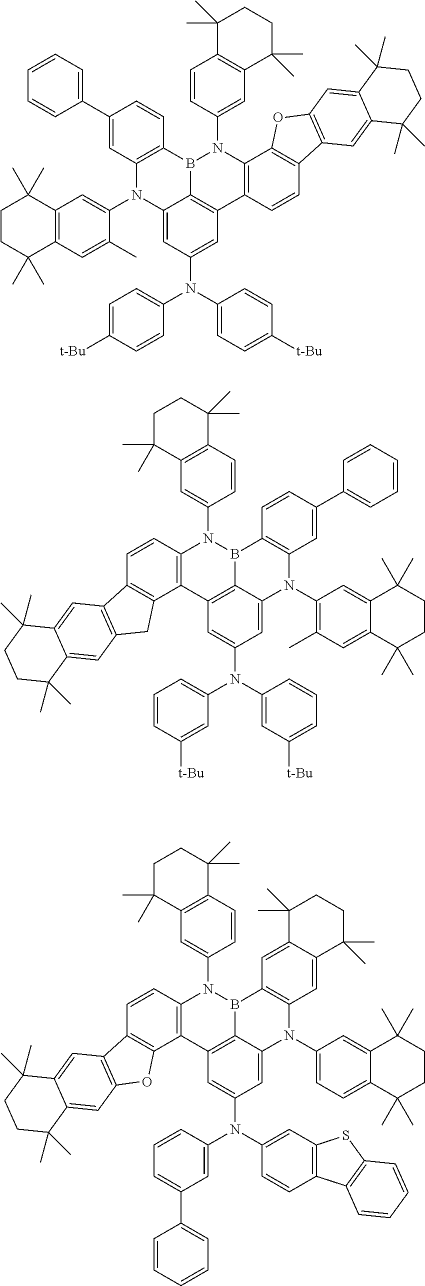 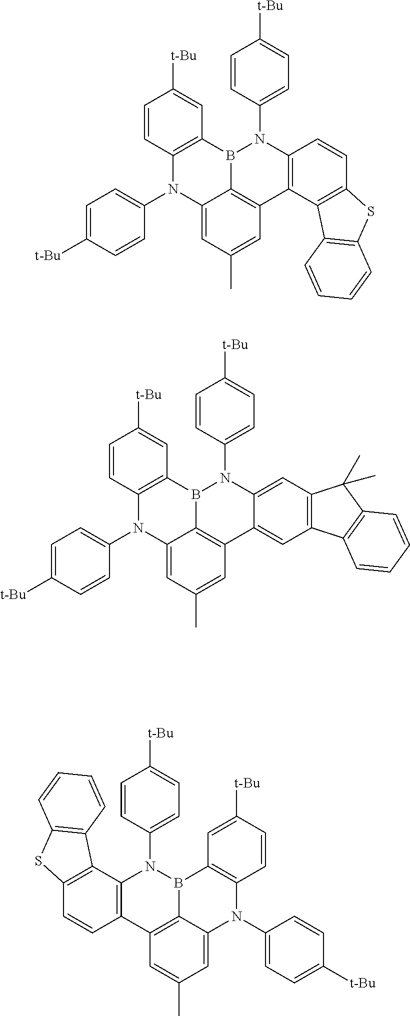 [SMILES: Cc1cc2c3c(c1)N(c1ccc(C(C)(C)C)cc1)c1ccc(C(C)(C)C)cc1B3N(c1ccc(C(C)(C)C)cc1)c1ccc3sc4ccccc4c3c1-2 ; Cc1cc2c3c(c1)N(c1ccc(C(C)(C)C)cc1)c1ccc(C(C)(C)C)cc1B3N(c1ccc(C(C)(C)C)cc1)c1cc3c(cc1-2)-c1ccccc1C3(C)C ; Cc1cc2c3c(c1)N(c1ccc(C(C)(C)C)cc1)c1ccc(C(C)(C)C)cc1B3N(c1ccc(C(C)(C)C)cc1)c1c-2ccc2sc3ccccc3c12] 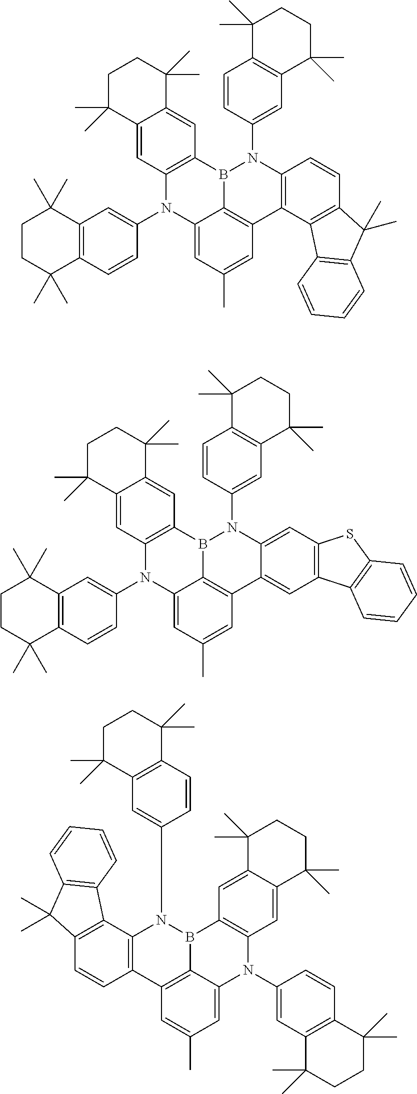 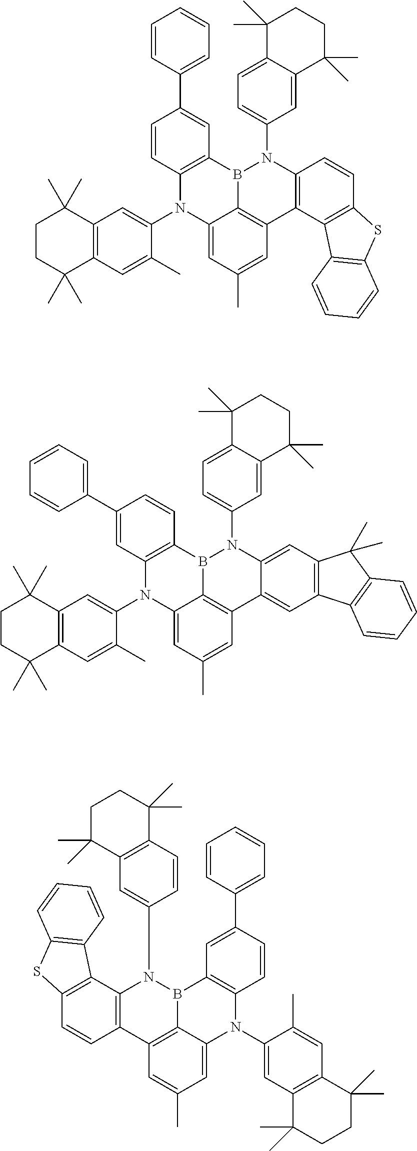 [SMILES: Cc1cc2c3c(c1)N(c1cc4c(cc1C)C(C)(C)CCC4(C)C)c1ccc(-c4ccccc4)cc1B3N(c1ccc3c(c1)C(C)(C)CCC3(C)C)c1ccc3sc4ccccc4c3c1-2 ; Cc1cc2c3c(c1)N(c1cc4c(cc1C)C(C)(C)CCC4(C)C)c1cc(-c4ccccc4)ccc1B3N(c1ccc3c(c1)C(C)(C)CCC3(C)C)c1cc3c(cc1-2)-c1ccccc1C3(C)C ; Cc1cc2c3c(c1)N(c1cc4c(cc1C)C(C)(C)CCC4(C)C)c1ccc(-c4ccccc4)cc1B3N(c1ccc3c(c1)C(C)(C)CCC3(C)C)c1c-2ccc2sc3ccccc3c12] 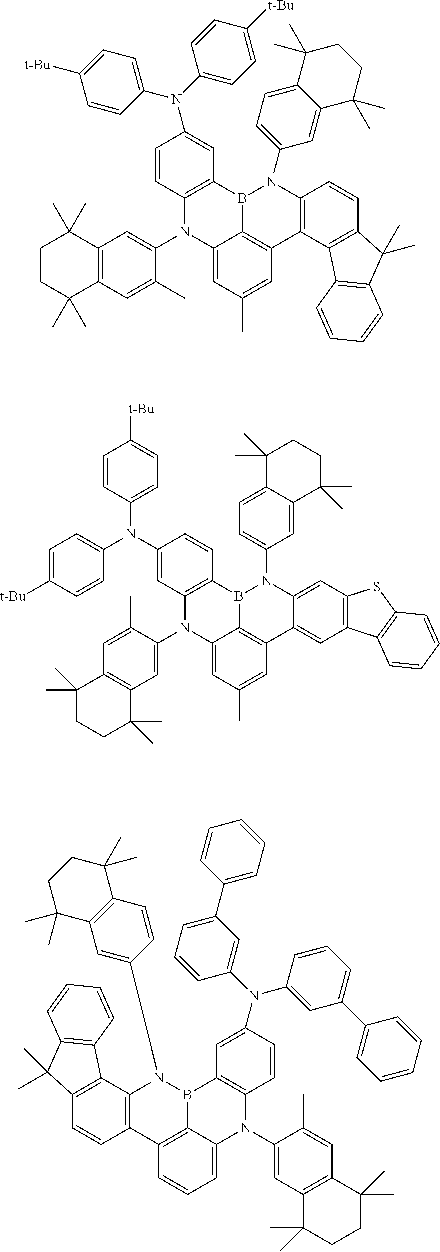 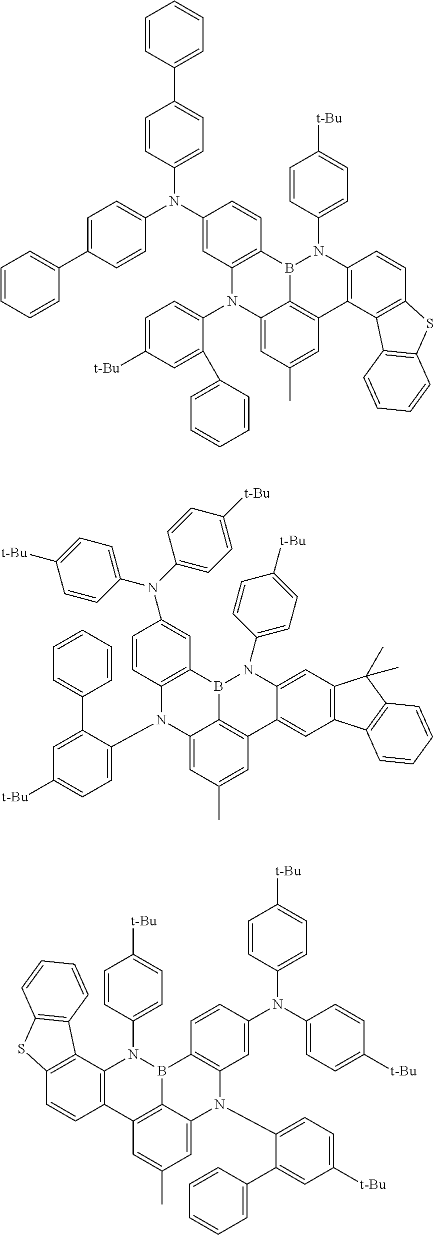 [SMILES: Cc1cc2c3c(c1)N(c1ccc(C(C)(C)C)cc1-c1ccccc1)c1cc(N(c4ccc(-c5ccccc5)cc4)c4ccc(-c5ccccc5)cc4)ccc1B3N(c1ccc(C(C)(C)C)cc1)c1ccc3sc4ccccc4c3c1-2 ; Cc1cc2c3c(c1)N(c1ccc(C(C)(C)C)cc1-c1ccccc1)c1ccc(N(c4ccc(C(C)(C)C)cc4)c4ccc(C(C)(C)C)cc4)cc1B3N(c1ccc(C(C)(C)C)cc1)c1cc3c(cc1-2)-c1ccccc1C3(C)C ; Cc1cc2c3c(c1)N(c1ccc(C(C)(C)C)cc1-c1ccccc1)c1cc(N(c4ccc(C(C)(C)C)cc4)c4ccc(C(C)(C)C)cc4)ccc1B3N(c1ccc(C(C)(C)C)cc1)c1c-2ccc2sc3ccccc3c12] 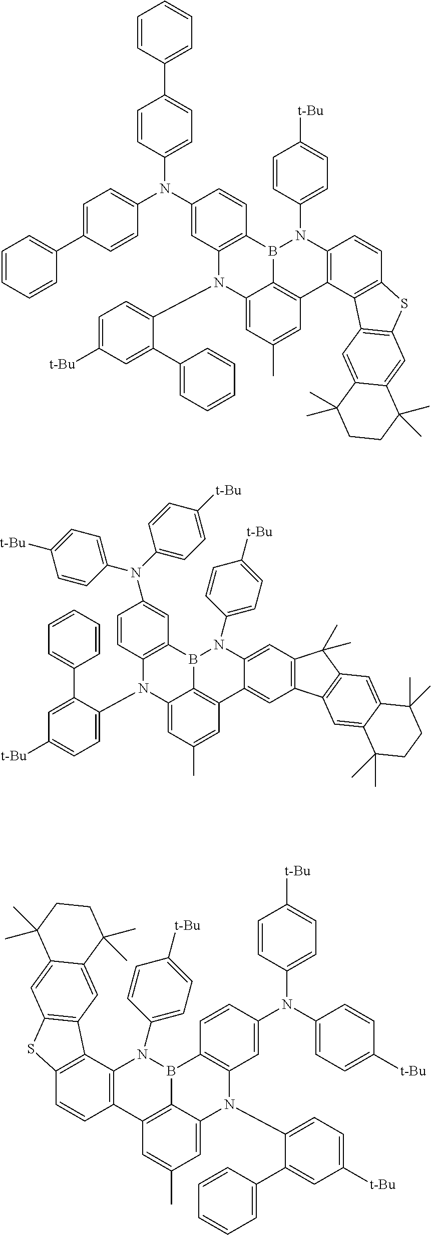 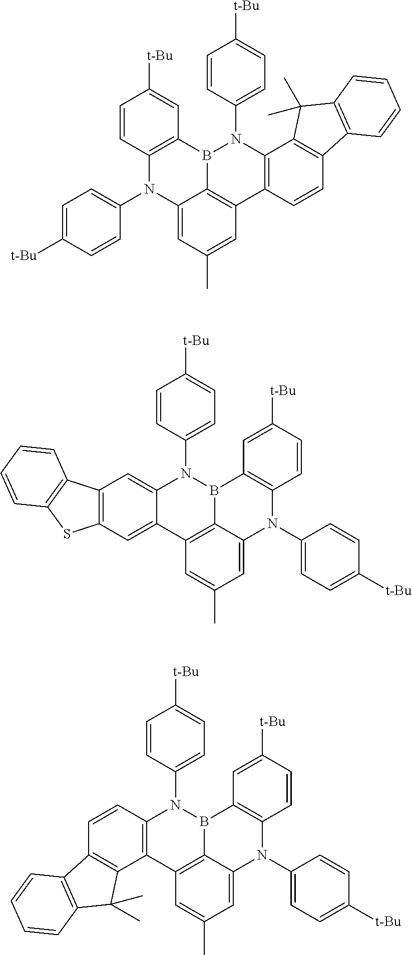 [SMILES: Cc1cc2c3c(c1)N(c1ccc(C(C)(C)C)cc1)c1ccc(C(C)(C)C)cc1B3N(c1ccc(C(C)(C)C)cc1)c1c-2ccc2c1C(C)(C)c1ccccc1-2 ; Cc1cc2c3c(c1)N(c1ccc(C(C)(C)C)cc1)c1ccc(C(C)(C)C)cc1B3N(c1ccc(C(C)(C)C)cc1)c1cc3c(cc1-2)sc1ccccc13 ; Cc1cc2c3c(c1)N(c1ccc(C(C)(C)C)cc1)c1ccc(C(C)(C)C)cc1B3N(c1ccc(C(C)(C)C)cc1)c1ccc3c(c1-2)C(C)(C)c1ccccc1-3] 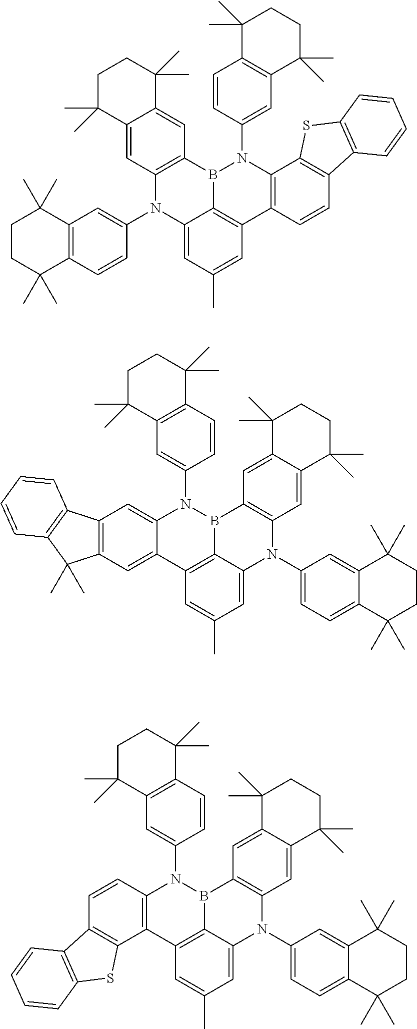 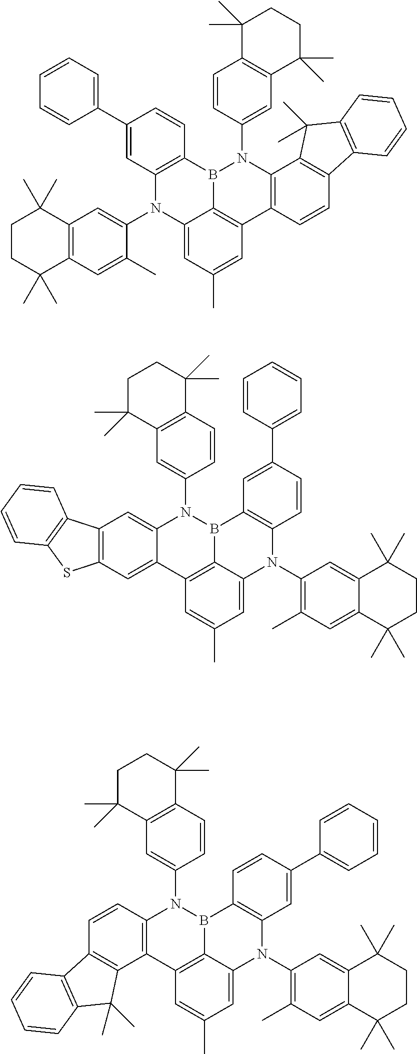 [SMILES: Cc1cc2c3c(c1)N(c1cc4c(cc1C)C(C)(C)CCC4(C)C)c1cc(-c4ccccc4)ccc1B3N(c1ccc3c(c1)C(C)(C)CCC3(C)C)c1c-2ccc2c1C(C)(C)c1ccccc1-2 ; Cc1cc2c3c(c1)N(c1cc4c(cc1C)C(C)(C)CCC4(C)C)c1ccc(-c4ccccc4)cc1B3N(c1ccc3c(c1)C(C)(C)CCC3(C)C)c1cc3c(cc1-2)sc1ccccc13 ; Cc1cc2c3c(c1)N(c1cc4c(cc1C)C(C)(C)CCC4(C)C)c1cc(-c4ccccc4)ccc1B3N(c1ccc3c(c1)C(C)(C)CCC3(C)C)c1ccc3c(c1-2)C(C)(C)c1ccccc1-3] 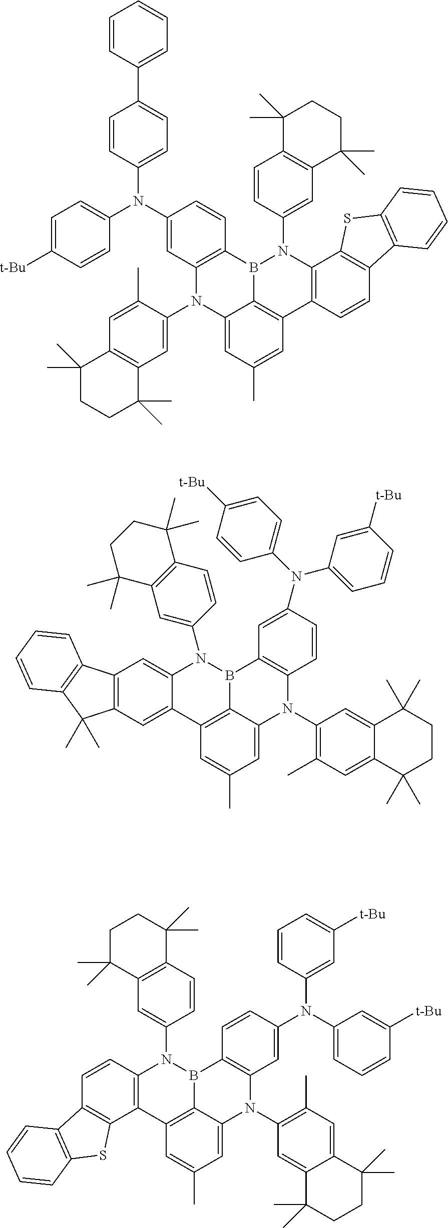 [SMILES: Cc1cc2c3c(c1)N(c1cc4c(cc1C)C(C)(C)CCC4(C)C)c1cc(N(c4ccc(-c5ccccc5)cc4)c4ccc(C(C)(C)C)cc4)ccc1B3N(c1ccc3c(c1)C(C)(C)CCC3(C)C)c1c-2ccc2c1sc1ccccc12 ; Cc1cc2c3c(c1)N(c1cc4c(cc1C)C(C)(C)CCC4(C)C)c1ccc(N(c4ccc(C(C)(C)C)cc4)c4cccc(C(C)(C)C)c4)cc1B3N(c1ccc3c(c1)C(C)(C)CCC3(C)C)c1cc3c(cc1-2)C(C)(C)c1ccccc1-3 ; Cc1cc2c3c(c1)N(c1cc4c(cc1C)C(C)(C)CCC4(C)C)c1cc(N(c4cccc(C(C)(C)C)c4)c4cccc(C(C)(C)C)c4)ccc1B3N(c1ccc3c(c1)C(C)(C)CCC3(C)C)c1ccc3c(sc4ccccc43)c1-2] 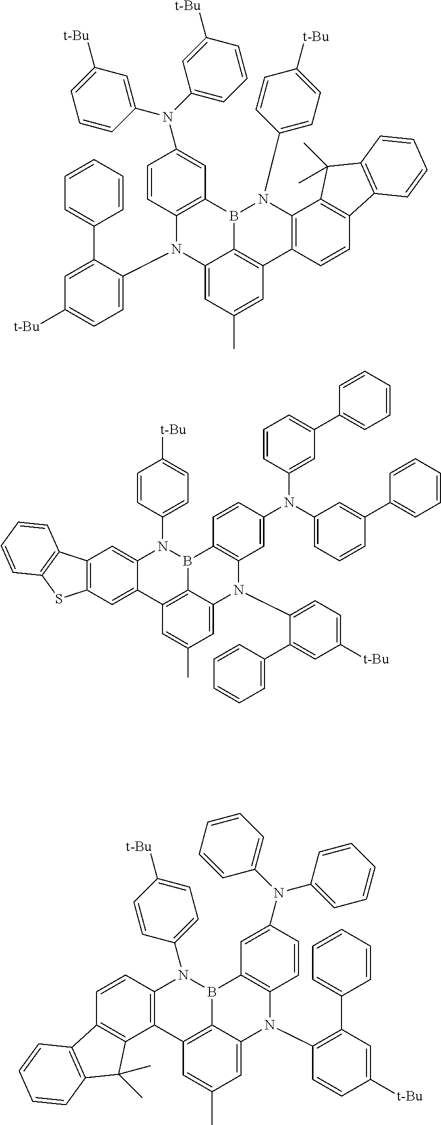 [SMILES: Cc1cc2c3c(c1)N(c1ccc(C(C)(C)C)cc1-c1ccccc1)c1ccc(N(c4cccc(C(C)(C)C)c4)c4cccc(C(C)(C)C)c4)cc1B3N(c1ccc(C(C)(C)C)cc1)c1c-2ccc2c1C(C)(C)c1ccccc1-2 ; Cc1cc2c3c(c1)N(c1ccc(C(C)(C)C)cc1-c1ccccc1)c1cc(N(c4cccc(-c5ccccc5)c4)c4cccc(-c5ccccc5)c4)ccc1B3N(c1ccc(C(C)(C)C)cc1)c1cc3c(cc1-2)sc1ccccc13 ; Cc1cc2c3c(c1)N(c1ccc(C(C)(C)C)cc1-c1ccccc1)c1ccc(N(c4ccccc4)c4ccccc4)cc1B3N(c1ccc(C(C)(C)C)cc1)c1ccc3c(c1-2)C(C)(C)c1ccccc1-3] 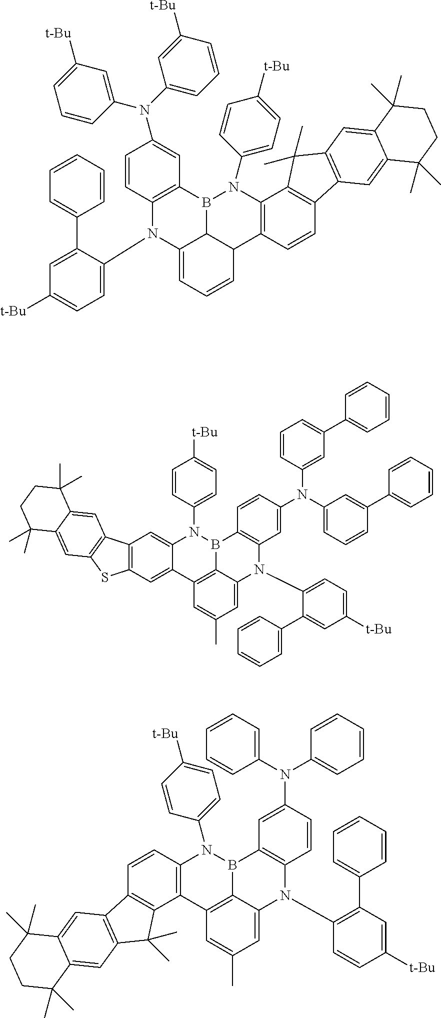 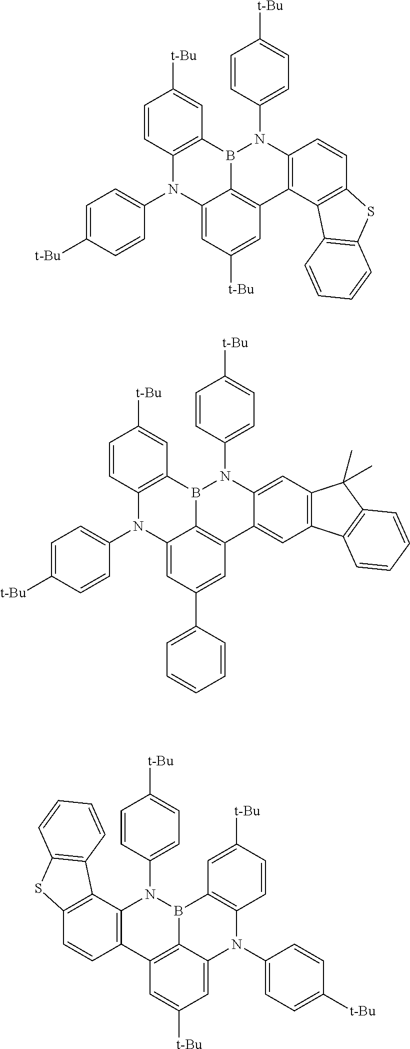 [SMILES: CC(C)(C)c1ccc(N2B3c4cc(C(C)(C)C)ccc4N(c4ccc(C(C)(C)C)cc4)c4cc(C(C)(C)C)cc(c43)-c3c2ccc2sc4ccccc4c32)cc1 ; CC(C)(C)c1ccc(N2B3c4cc(C(C)(C)C)ccc4N(c4ccc(C(C)(C)C)cc4)c4cc(-c5ccccc5)cc(c43)-c3cc4c(cc32)C(C)(C)c2ccccc2-4)cc1 ; CC(C)(C)c1ccc(N2B3c4cc(C(C)(C)C)ccc4N(c4ccc(C(C)(C)C)cc4)c4cc(C(C)(C)C)cc(c43)-c3ccc4sc5ccccc5c4c32)cc1] 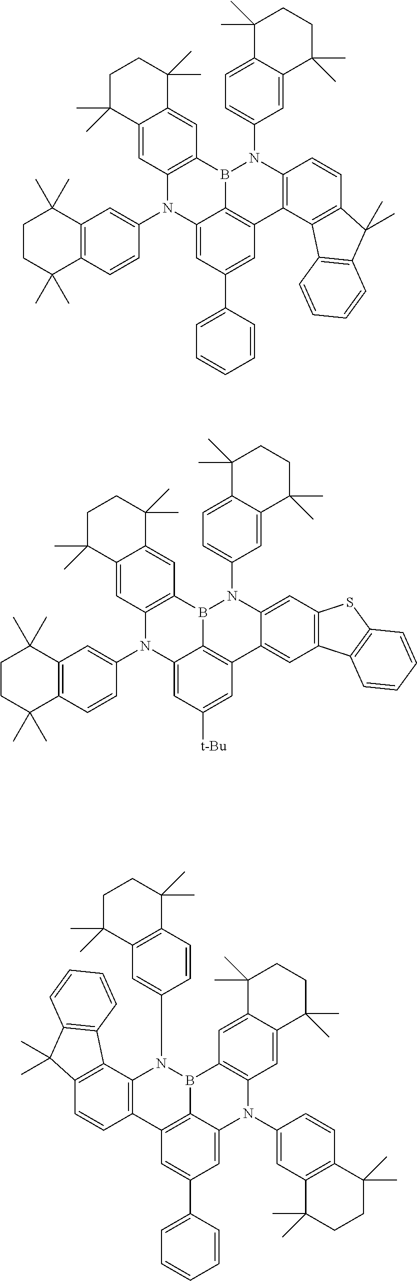 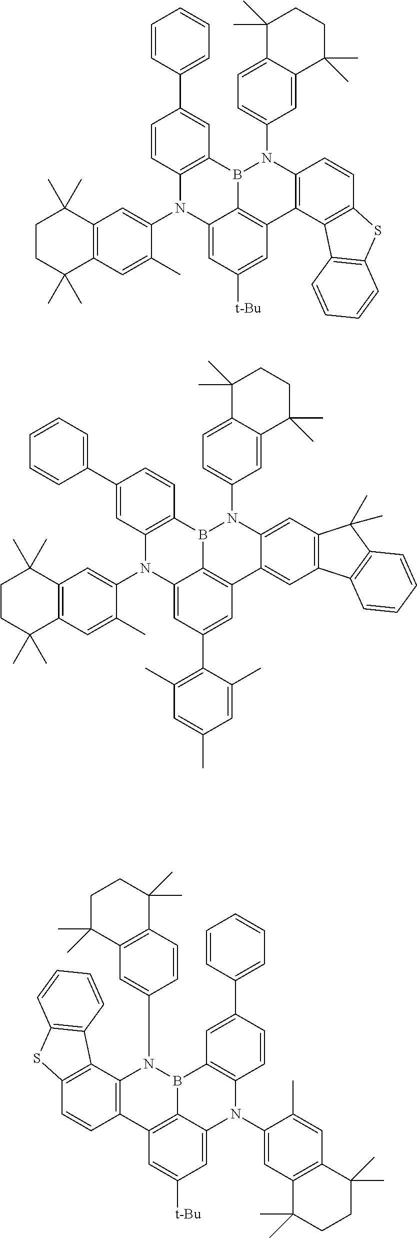 [SMILES: Cc1cc2c(cc1N1c3ccc(-c4ccccc4)cc3B3c4c(cc(C(C)(C)C)cc41)-c1c(ccc4sc5ccccc5c14)N3c1ccc3c(c1)C(C)(C)CCC3(C)C)C(C)(C)CCC2(C)C ; Cc1cc(C)c(-c2cc3c4c(c2)N(c2cc5c(cc2C)C(C)(C)CCC5(C)C)c2cc(-c5ccccc5)ccc2B4N(c2ccc4c(c2)C(C)(C)CCC4(C)C)c2cc4c(cc2-3)-c2ccccc2C4(C)C)c(C)c1 ; Cc1cc2c(cc1N1c3ccc(-c4ccccc4)cc3B3c4c(cc(C(C)(C)C)cc41)-c1ccc4sc5ccccc5c4c1N3c1ccc3c(c1)C(C)(C)CCC3(C)C)C(C)(C)CCC2(C)C] 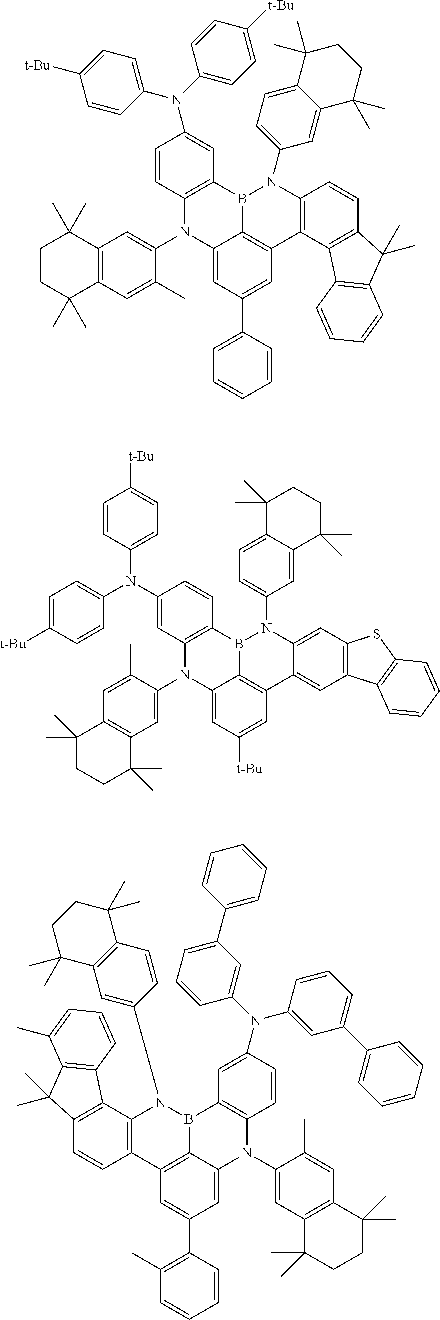 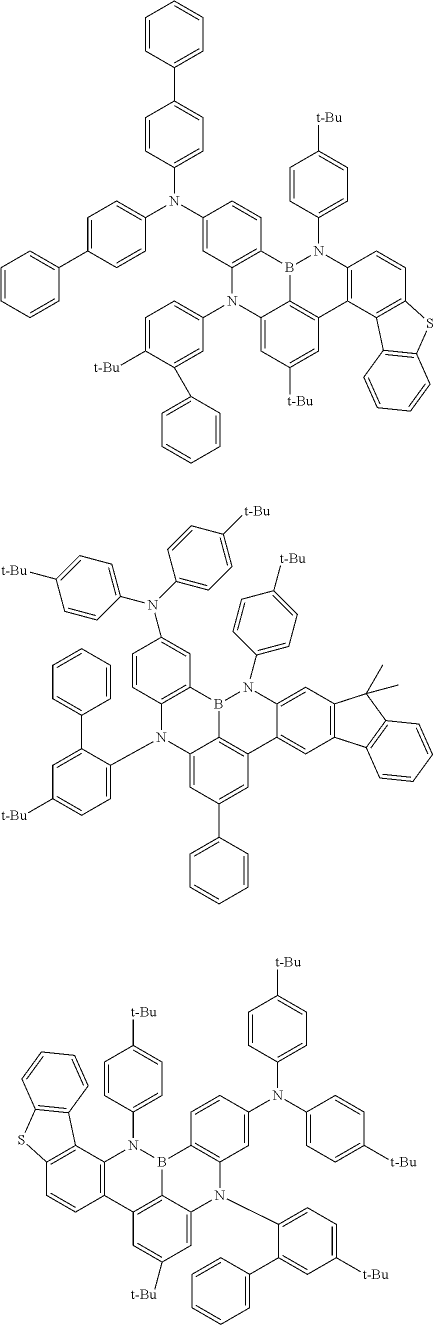 [SMILES: CC(C)(C)c1ccc(N2B3c4ccc(N(c5ccc(-c6ccccc6)cc5)c5ccc(-c6ccccc6)cc5)cc4N(c4ccc(C(C)(C)C)c(-c5ccccc5)c4)c4cc(C(C)(C)C)cc(c43)-c3c2ccc2sc4ccccc4c32)cc1 ; CC(C)(C)c1ccc(N2B3c4cc(N(c5ccc(C(C)(C)C)cc5)c5ccc(C(C)(C)C)cc5)ccc4N(c4ccc(C(C)(C)C)cc4-c4ccccc4)c4cc(-c5ccccc5)cc(c43)-c3cc4c(cc32)C(C)(C)c2ccccc2-4)cc1 ; CC(C)(C)c1ccc(N2B3c4ccc(N(c5ccc(C(C)(C)C)cc5)c5ccc(C(C)(C)C)cc5)cc4N(c4ccc(C(C)(C)C)cc4-c4ccccc4)c4cc(C(C)(C)C)cc(c43)-c3ccc4sc5ccccc5c4c32)cc1] 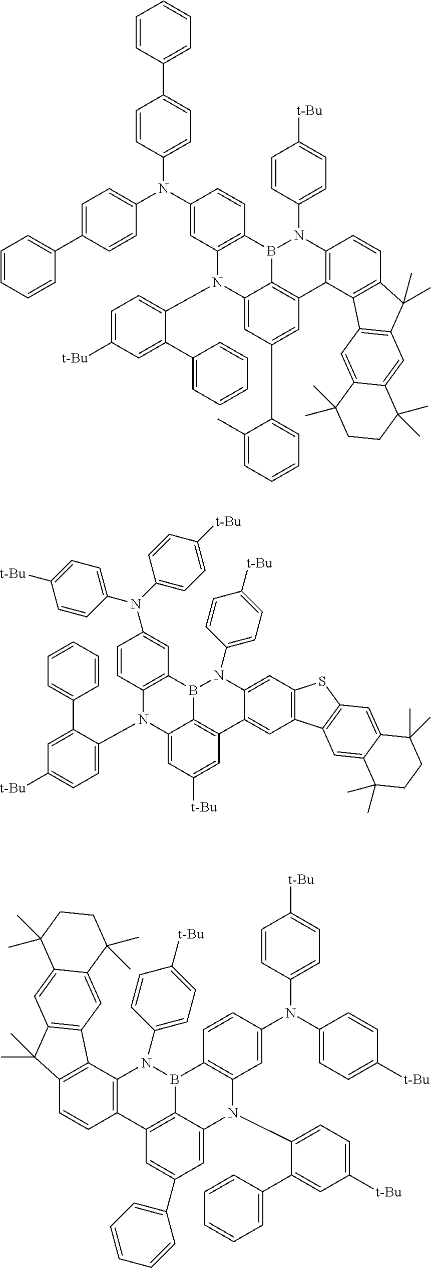 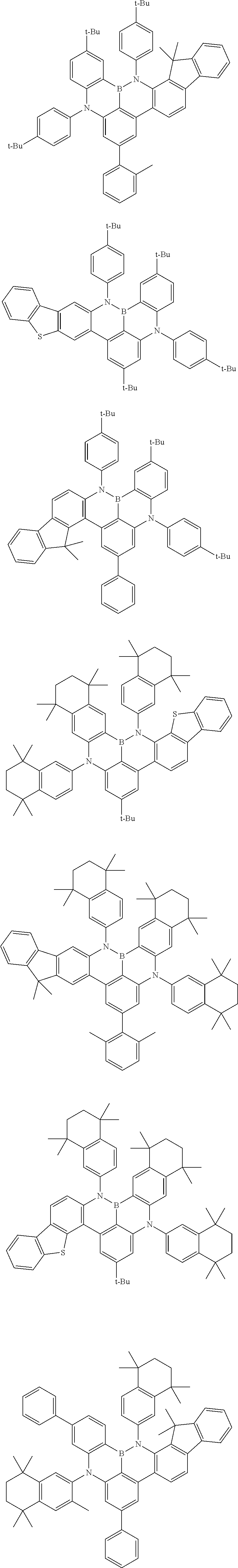 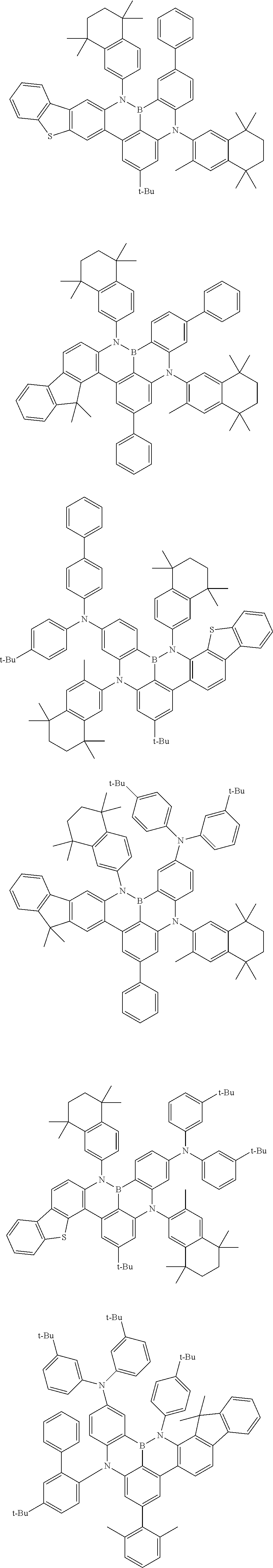 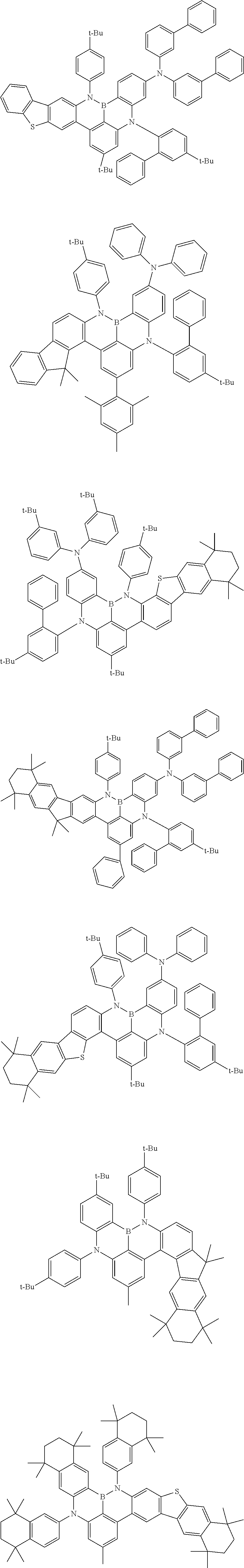 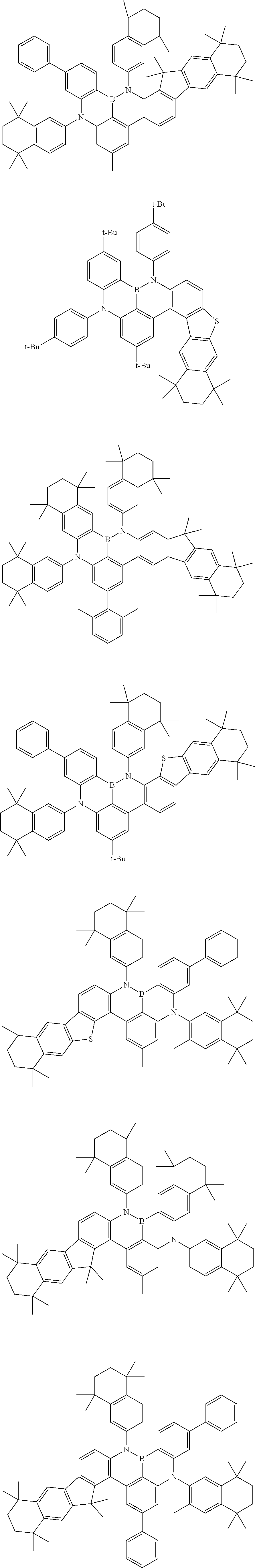 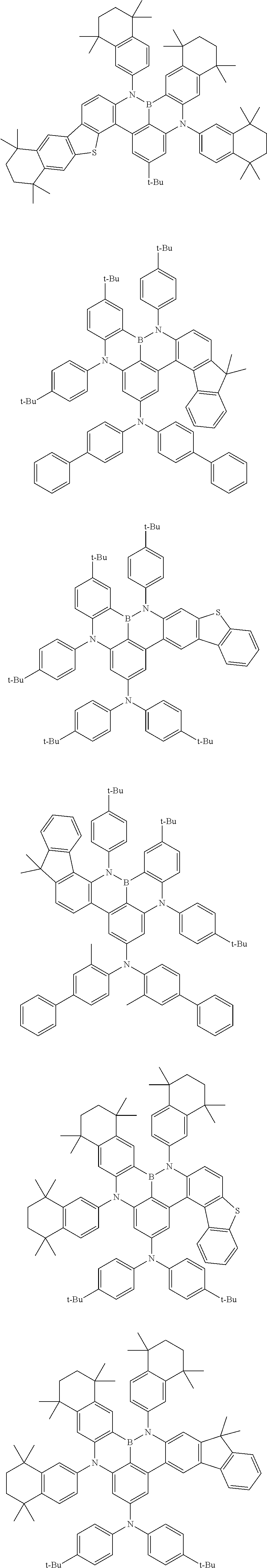 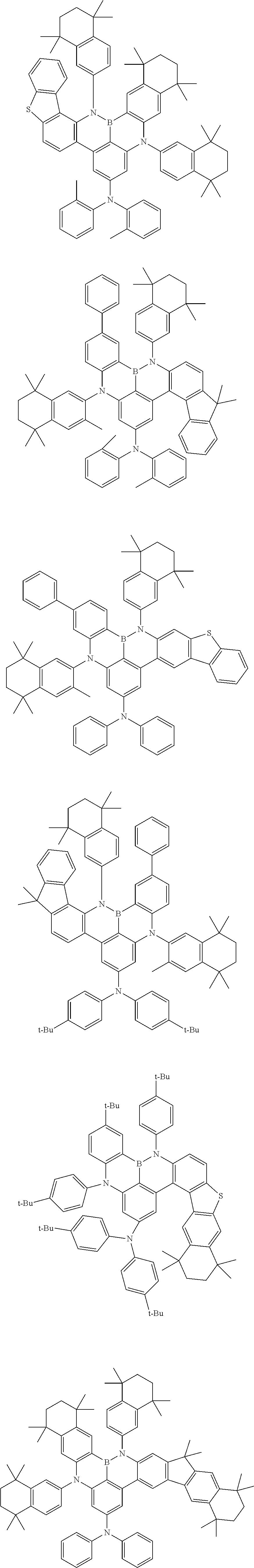 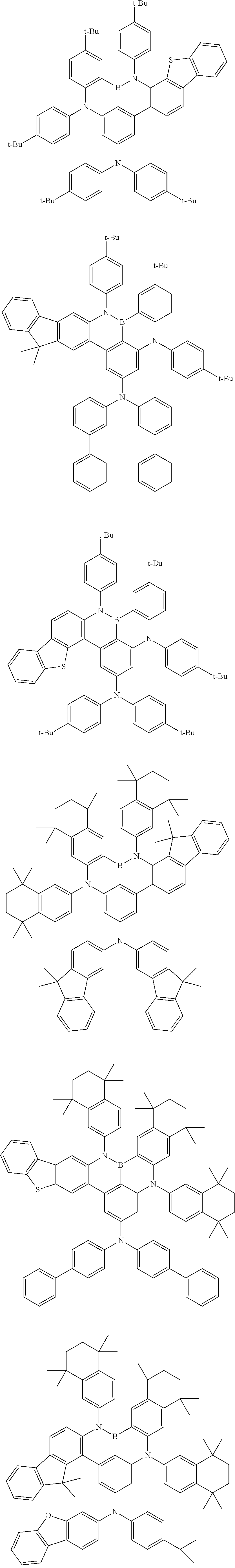 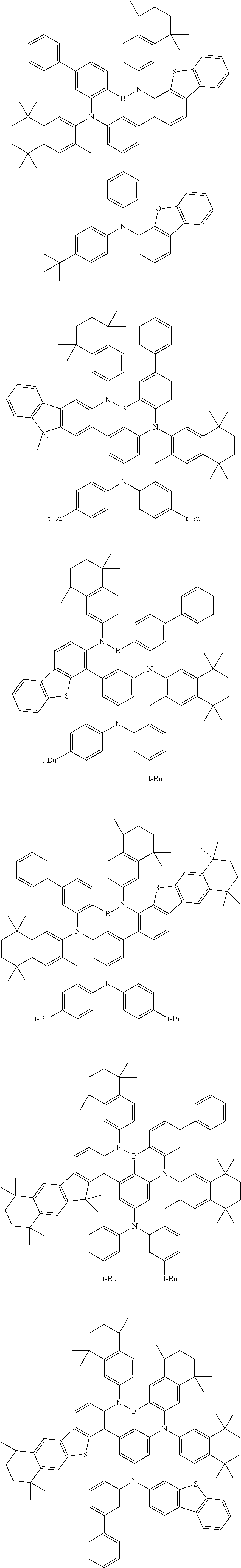 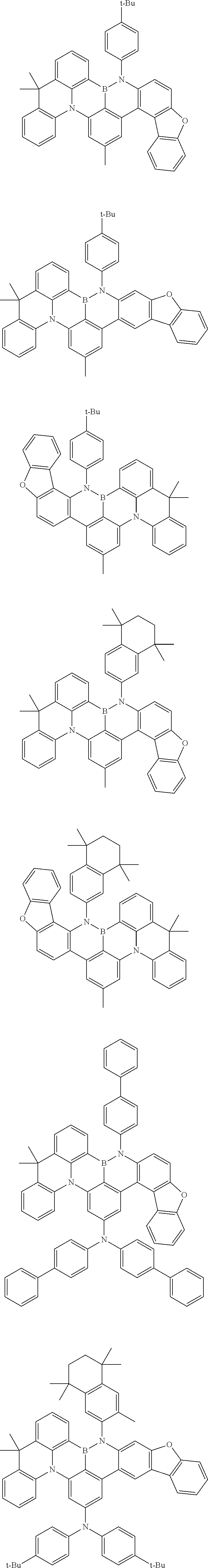 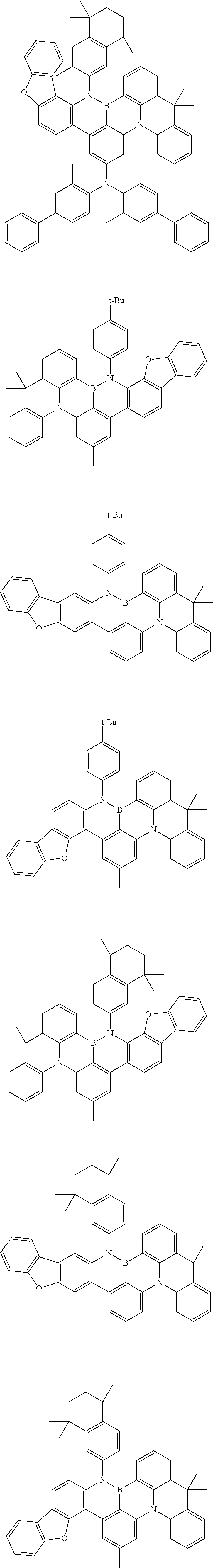 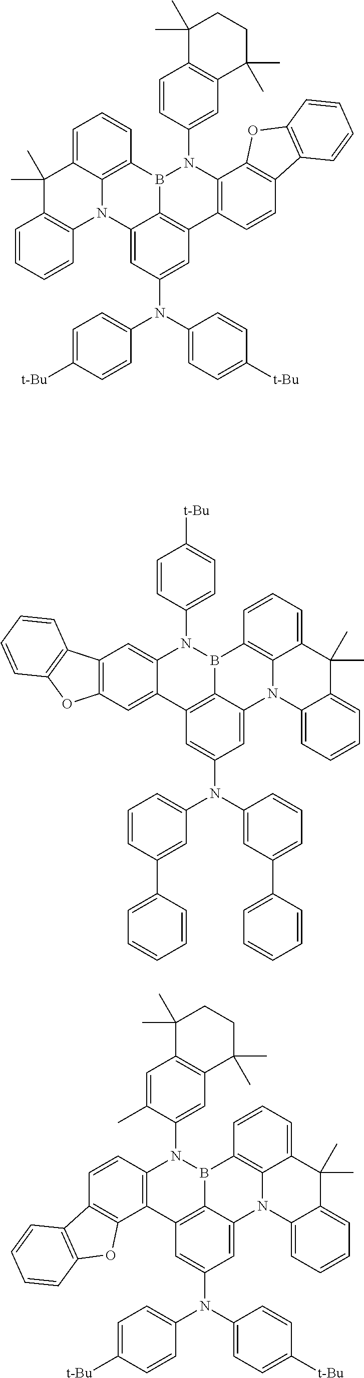 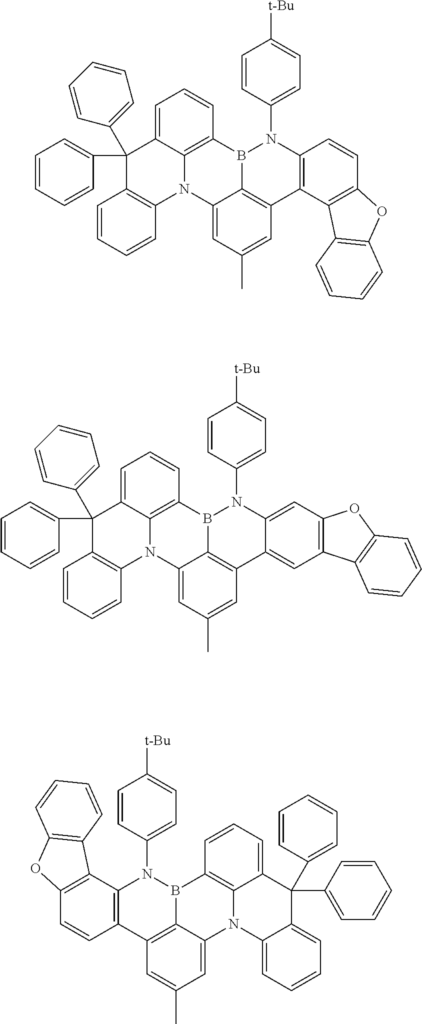 [SMILES: Cc1cc2c3c(c1)N1c4ccccc4C(c4ccccc4)(c4ccccc4)c4cccc(c41)B3N(c1ccc(C(C)(C)C)cc1)c1ccc3oc4ccccc4c3c1-2 ; Cc1cc2c3c(c1)N1c4ccccc4C(c4ccccc4)(c4ccccc4)c4cccc(c41)B3N(c1ccc(C(C)(C)C)cc1)c1cc3oc4ccccc4c3cc1-2 ; Cc1cc2c3c(c1)N1c4ccccc4C(c4ccccc4)(c4ccccc4)c4cccc(c41)B3N(c1ccc(C(C)(C)C)cc1)c1c-2ccc2oc3ccccc3c12] 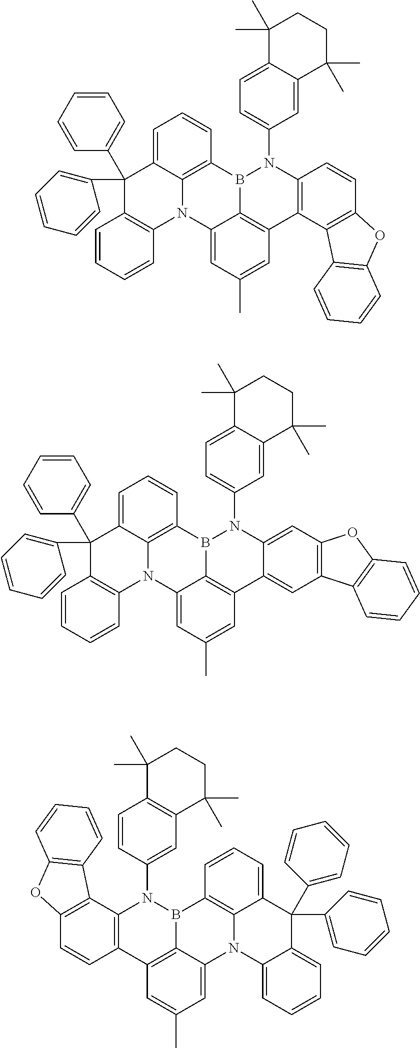 [SMILES: Cc1cc2c3c(c1)N1c4ccccc4C(c4ccccc4)(c4ccccc4)c4cccc(c41)B3N(c1ccc3c(c1)C(C)(C)CCC3(C)C)c1ccc3oc4ccccc4c3c1-2 ; Cc1cc2c3c(c1)N1c4ccccc4C(c4ccccc4)(c4ccccc4)c4cccc(c41)B3N(c1ccc3c(c1)C(C)(C)CCC3(C)C)c1cc3oc4ccccc4c3cc1-2 ; Cc1cc2c3c(c1)N1c4ccccc4C(c4ccccc4)(c4ccccc4)c4cccc(c41)B3N(c1ccc3c(c1)C(C)(C)CCC3(C)C)c1c-2ccc2oc3ccccc3c12] 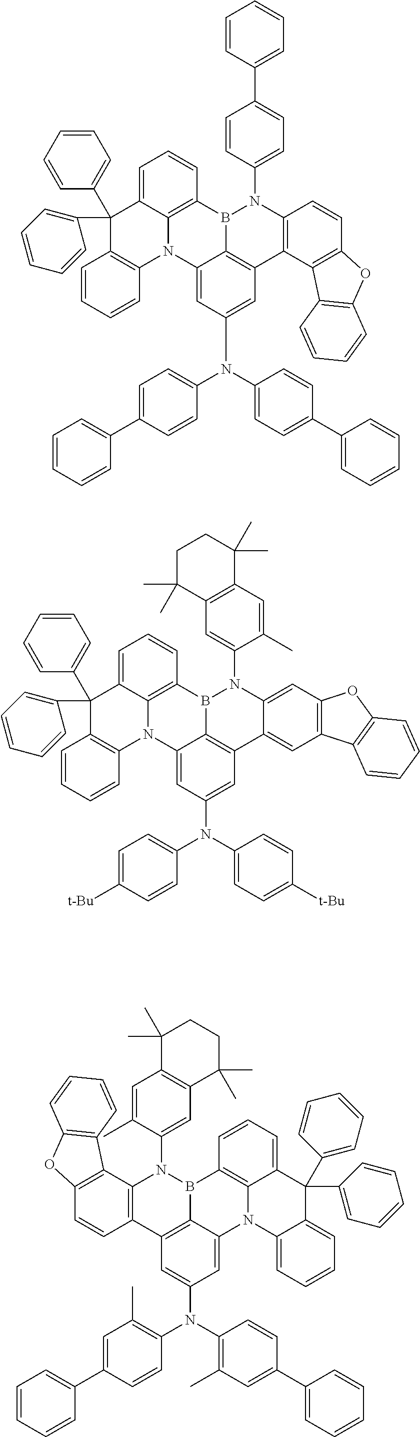 [SMILES: c1ccc(-c2ccc(N3B4c5cccc6c5N(c5ccccc5C6(c5ccccc5)c5ccccc5)c5cc(N(c6ccc(-c7ccccc7)cc6)c6ccc(-c7ccccc7)cc6)cc(c54)-c4c3ccc3oc5ccccc5c43)cc2)cc1 ; Cc1cc2c(cc1N1B3c4cccc5c4N(c4ccccc4C5(c4ccccc4)c4ccccc4)c4cc(N(c5ccc(C(C)(C)C)cc5)c5ccc(C(C)(C)C)cc5)cc(c43)-c3cc4c(cc31)oc1ccccc14)C(C)(C)CCC2(C)C ; Cc1cc2c(cc1N1B3c4cccc5c4N(c4ccccc4C5(c4ccccc4)c4ccccc4)c4cc(N(c5ccc(-c6ccccc6)cc5C)c5ccc(-c6ccccc6)cc5C)cc(c43)-c3ccc4oc5ccccc5c4c31)C(C)(C)CCC2(C)C] 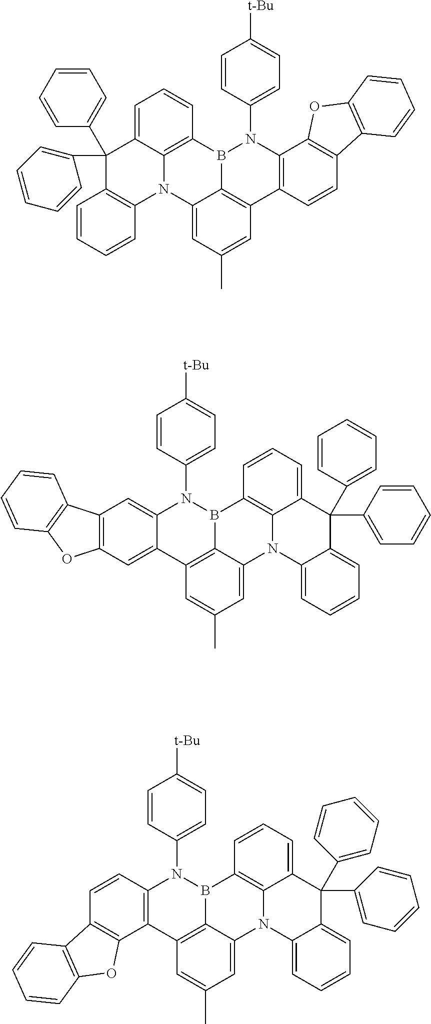 [SMILES: Cc1cc2c3c(c1)N1c4ccccc4C(c4ccccc4)(c4ccccc4)c4cccc(c41)B3N(c1ccc(C(C)(C)C)cc1)c1c-2ccc2c1oc1ccccc12 ; Cc1cc2c3c(c1)N1c4ccccc4C(c4ccccc4)(c4ccccc4)c4cccc(c41)B3N(c1ccc(C(C)(C)C)cc1)c1cc3c(cc1-2)oc1ccccc13 ; Cc1cc2c3c(c1)N1c4ccccc4C(c4ccccc4)(c4ccccc4)c4cccc(c41)B3N(c1ccc(C(C)(C)C)cc1)c1ccc3c(oc4ccccc43)c1-2] 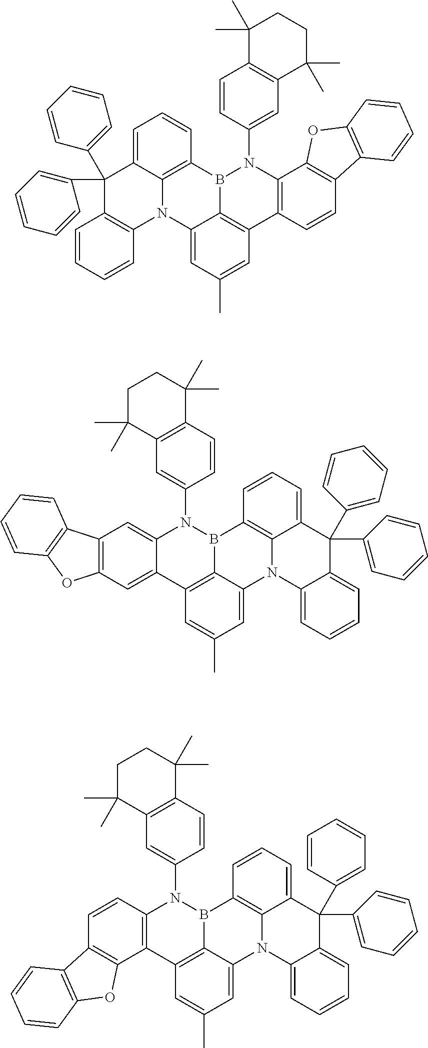 [SMILES: Cc1cc2c3c(c1)N1c4ccccc4C(c4ccccc4)(c4ccccc4)c4cccc(c41)B3N(c1ccc3c(c1)C(C)(C)CCC3(C)C)c1c-2ccc2c1oc1ccccc12 ; Cc1cc2c3c(c1)N1c4ccccc4C(c4ccccc4)(c4ccccc4)c4cccc(c41)B3N(c1ccc3c(c1)C(C)(C)CCC3(C)C)c1cc3c(cc1-2)oc1ccccc13 ; Cc1cc2c3c(c1)N1c4ccccc4C(c4ccccc4)(c4ccccc4)c4cccc(c41)B3N(c1ccc3c(c1)C(C)(C)CCC3(C)C)c1ccc3c(oc4ccccc43)c1-2] 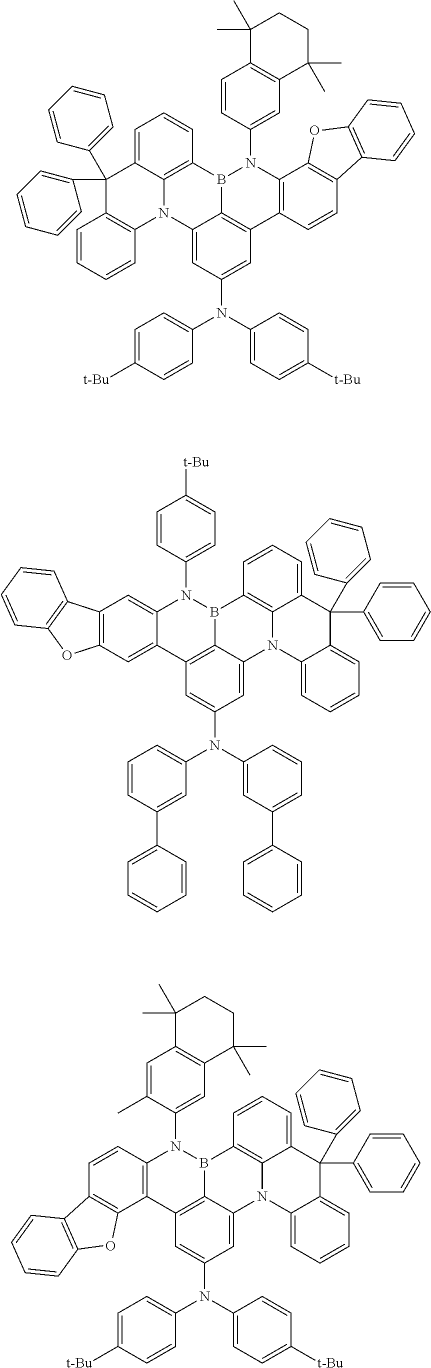 [SMILES: CC(C)(C)c1ccc(N(c2ccc(C(C)(C)C)cc2)c2cc3c4c(c2)N2c5ccccc5C(c5ccccc5)(c5ccccc5)c5cccc(c52)B4N(c2ccc4c(c2)C(C)(C)CCC4(C)C)c2c-3ccc3c2oc2ccccc23)cc1 ; CC(C)(C)c1ccc(N2B3c4cccc5c4N(c4ccccc4C5(c4ccccc4)c4ccccc4)c4cc(N(c5cccc(-c6ccccc6)c5)c5cccc(-c6ccccc6)c5)cc(c43)-c3cc4oc5ccccc5c4cc32)cc1 ; Cc1cc2c(cc1N1B3c4cccc5c4N(c4ccccc4C5(c4ccccc4)c4ccccc4)c4cc(N(c5ccc(C(C)(C)C)cc5)c5ccc(C(C)(C)C)cc5)cc(c43)-c3c1ccc1c3oc3ccccc31)C(C)(C)CCC2(C)C] 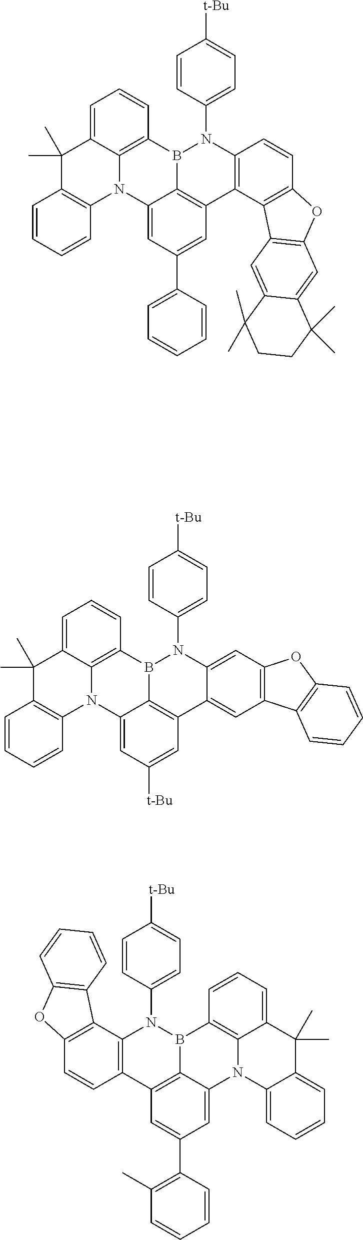 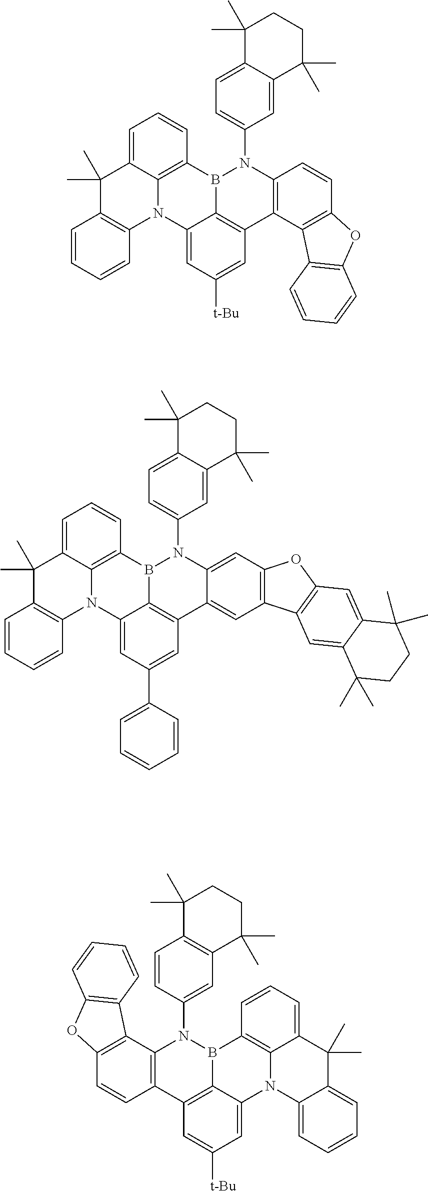 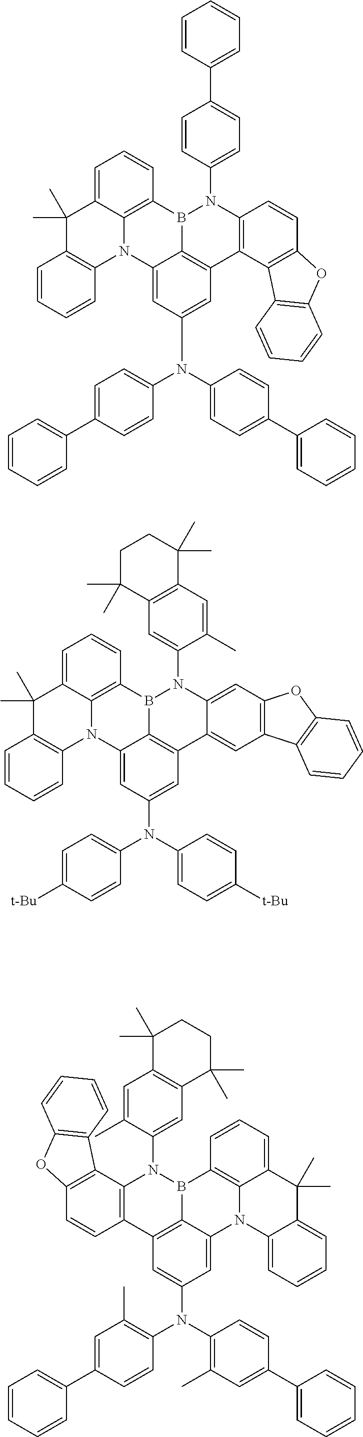 [SMILES: CC1(C)c2ccccc2N2c3cc(N(c4ccc(-c5ccccc5)cc4)c4ccc(-c5ccccc5)cc4)cc4c3B(c3cccc1c32)N(c1ccc(-c2ccccc2)cc1)c1ccc2oc3ccccc3c2c1-4 ; Cc1cc2c(cc1N1B3c4cccc5c4N(c4ccccc4C5(C)C)c4cc(N(c5ccc(C(C)(C)C)cc5)c5ccc(C(C)(C)C)cc5)cc(c43)-c3cc4c(cc31)oc1ccccc14)C(C)(C)CCC2(C)C ; Cc1cc2c(cc1N1B3c4cccc5c4N(c4ccccc4C5(C)C)c4cc(N(c5ccc(-c6ccccc6)cc5C)c5ccc(-c6ccccc6)cc5C)cc(c43)-c3ccc4oc5ccccc5c4c31)C(C)(C)CCC2(C)C] 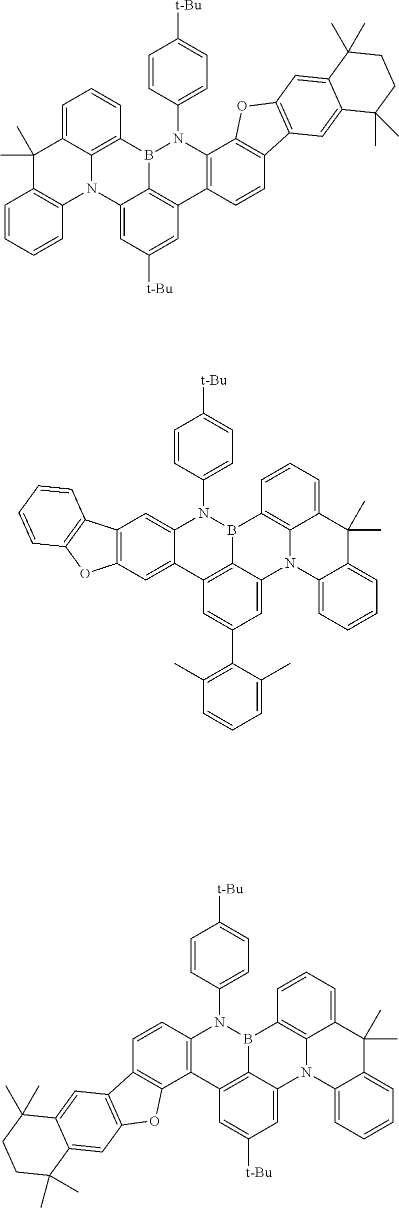 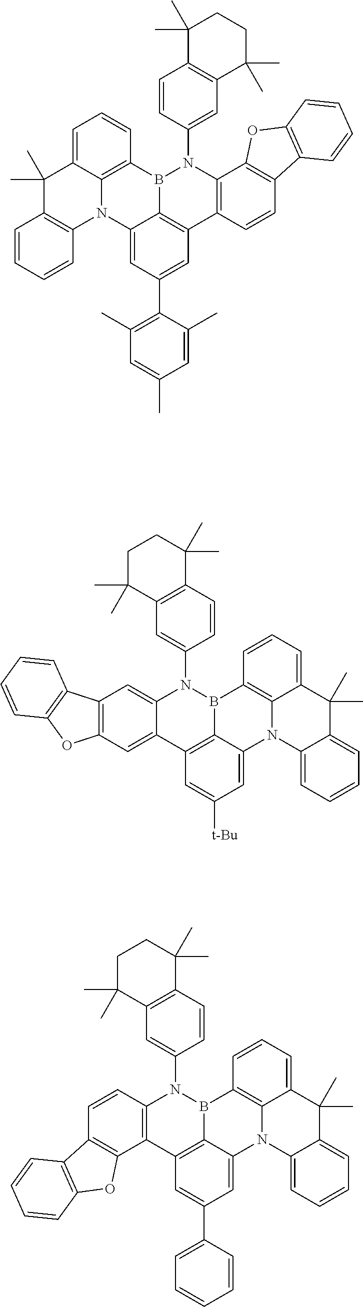 [SMILES: Cc1cc(C)c(-c2cc3c4c(c2)N2c5ccccc5C(C)(C)c5cccc(c52)B4N(c2ccc4c(c2)C(C)(C)CCC4(C)C)c2c-3ccc3c2oc2ccccc23)c(C)c1 ; CC(C)(C)c1cc2c3c(c1)N1c4ccccc4C(C)(C)c4cccc(c41)B3N(c1ccc3c(c1)C(C)(C)CCC3(C)C)c1cc3c(cc1-2)oc1ccccc13 ; CC1(C)CCC(C)(C)c2cc(N3B4c5cccc6c5N(c5ccccc5C6(C)C)c5cc(-c6ccccc6)cc(c54)-c4c3ccc3c4oc4ccccc43)ccc21] 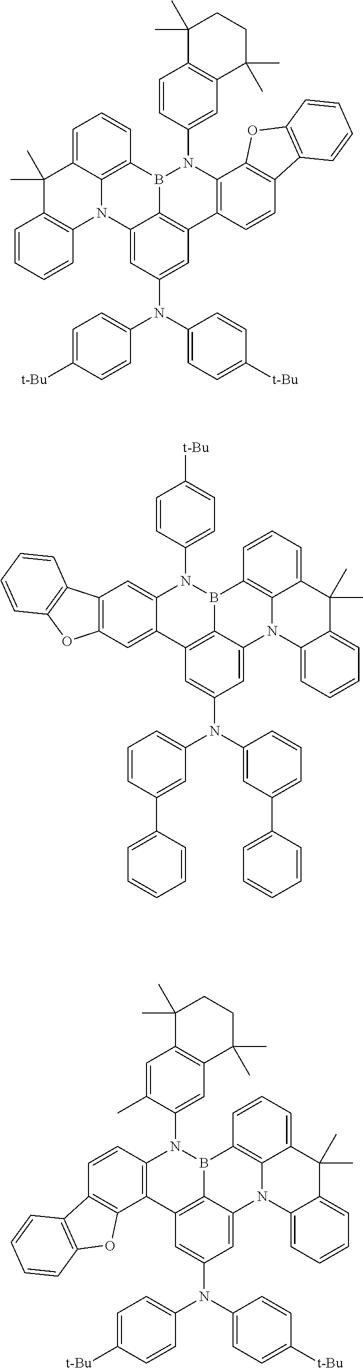 [SMILES: CC(C)(C)c1ccc(N(c2ccc(C(C)(C)C)cc2)c2cc3c4c(c2)N2c5ccccc5C(C)(C)c5cccc(c52)B4N(c2ccc4c(c2)C(C)(C)CCC4(C)C)c2c-3ccc3c2oc2ccccc23)cc1 ; CC(C)(C)c1ccc(N2B3c4cccc5c4N(c4ccccc4C5(C)C)c4cc(N(c5cccc(-c6ccccc6)c5)c5cccc(-c6ccccc6)c5)cc(c43)-c3cc4oc5ccccc5c4cc32)cc1 ; Cc1cc2c(cc1N1B3c4cccc5c4N(c4ccccc4C5(C)C)c4cc(N(c5ccc(C(C)(C)C)cc5)c5ccc(C(C)(C)C)cc5)cc(c43)-c3c1ccc1c3oc3ccccc31)C(C)(C)CCC2(C)C] 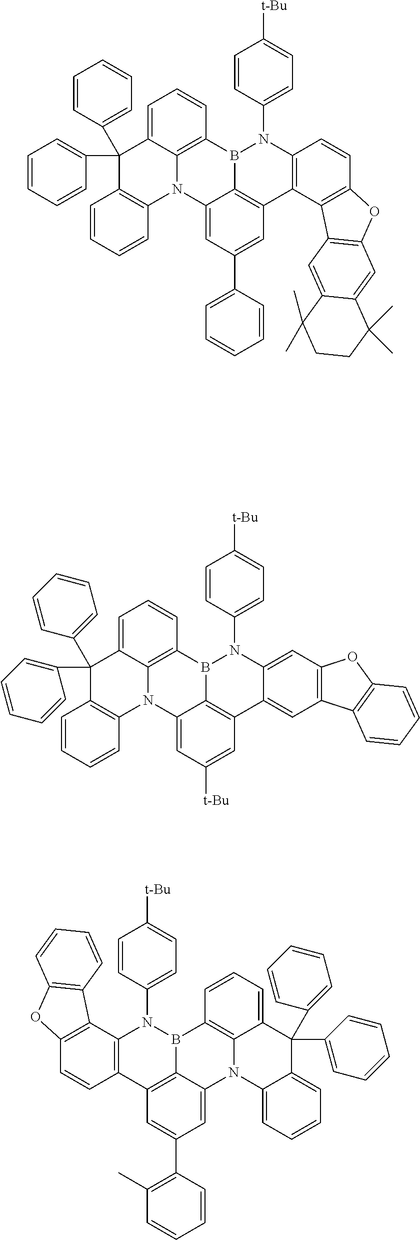 [SMILES: CC(C)(C)c1ccc(N2B3c4cccc5c4N(c4ccccc4C5(c4ccccc4)c4ccccc4)c4cc(-c5ccccc5)cc(c43)-c3c2ccc2oc4cc5c(cc4c32)C(C)(C)CCC5(C)C)cc1 ; CC(C)(C)c1ccc(N2B3c4cccc5c4N(c4ccccc4C5(c4ccccc4)c4ccccc4)c4cc(C(C)(C)C)cc(c43)-c3cc4c(cc32)oc2ccccc24)cc1 ; Cc1ccccc1-c1cc2c3c(c1)N1c4ccccc4C(c4ccccc4)(c4ccccc4)c4cccc(c41)B3N(c1ccc(C(C)(C)C)cc1)c1c-2ccc2oc3ccccc3c12] 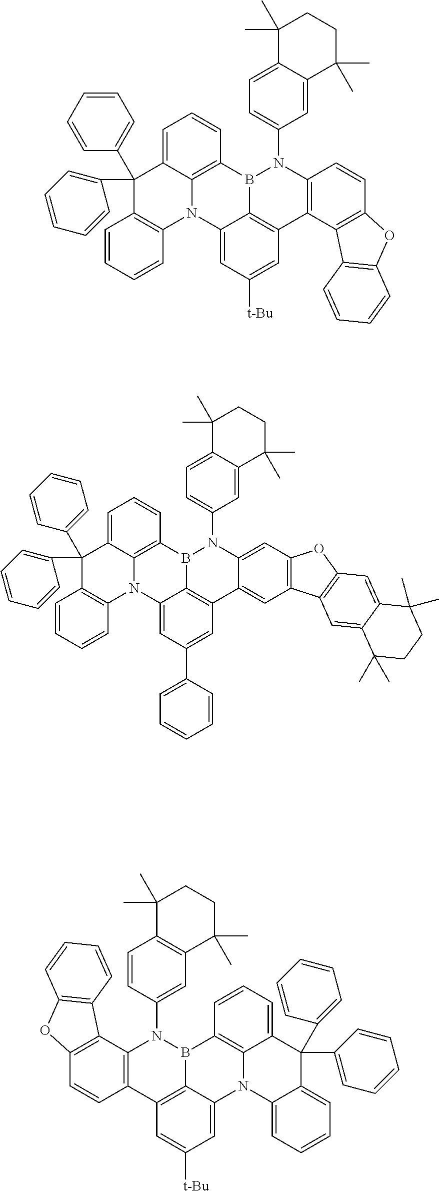 [SMILES: CC(C)(C)c1cc2c3c(c1)N1c4ccccc4C(c4ccccc4)(c4ccccc4)c4cccc(c41)B3N(c1ccc3c(c1)C(C)(C)CCC3(C)C)c1ccc3oc4ccccc4c3c1-2 ; CC1(C)CCC(C)(C)c2cc(N3B4c5cccc6c5N(c5ccccc5C6(c5ccccc5)c5ccccc5)c5cc(-c6ccccc6)cc(c54)-c4cc5c(cc43)oc3cc4c(cc35)C(C)(C)CCC4(C)C)ccc21 ; CC(C)(C)c1cc2c3c(c1)N1c4ccccc4C(c4ccccc4)(c4ccccc4)c4cccc(c41)B3N(c1ccc3c(c1)C(C)(C)CCC3(C)C)c1c-2ccc2oc3ccccc3c12] 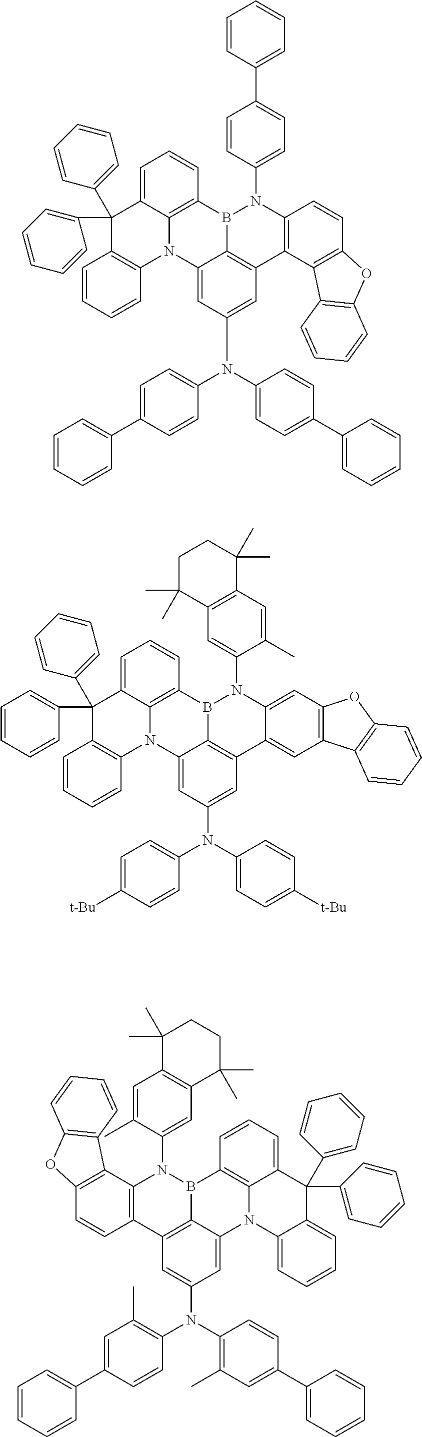 [SMILES: c1ccc(-c2ccc(N3B4c5cccc6c5N(c5ccccc5C6(c5ccccc5)c5ccccc5)c5cc(N(c6ccc(-c7ccccc7)cc6)c6ccc(-c7ccccc7)cc6)cc(c54)-c4c3ccc3oc5ccccc5c43)cc2)cc1 ; Cc1cc2c(cc1N1B3c4cccc5c4N(c4ccccc4C5(c4ccccc4)c4ccccc4)c4cc(N(c5ccc(C(C)(C)C)cc5)c5ccc(C(C)(C)C)cc5)cc(c43)-c3cc4c(cc31)oc1ccccc14)C(C)(C)CCC2(C)C ; Cc1cc2c(cc1N1B3c4cccc5c4N(c4ccccc4C5(c4ccccc4)c4ccccc4)c4cc(N(c5ccc(-c6ccccc6)cc5C)c5ccc(-c6ccccc6)cc5C)cc(c43)-c3ccc4oc5ccccc5c4c31)C(C)(C)CCC2(C)C] 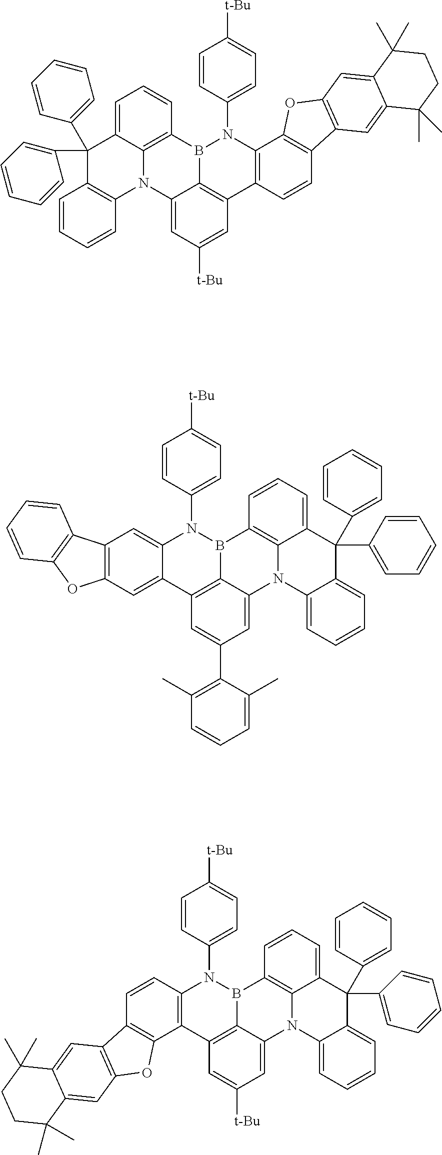 [SMILES: CC(C)(C)c1ccc(N2B3c4cccc5c4N(c4ccccc4C5(c4ccccc4)c4ccccc4)c4cc(C(C)(C)C)cc(c43)-c3ccc4c(oc5cc6c(cc54)C(C)(C)CCC6(C)C)c32)cc1 ; Cc1cccc(C)c1-c1cc2c3c(c1)N1c4ccccc4C(c4ccccc4)(c4ccccc4)c4cccc(c41)B3N(c1ccc(C(C)(C)C)cc1)c1cc3c(cc1-2)oc1ccccc13 ; CC(C)(C)c1ccc(N2B3c4cccc5c4N(c4ccccc4C5(c4ccccc4)c4ccccc4)c4cc(C(C)(C)C)cc(c43)-c3c2ccc2c3oc3cc4c(cc32)C(C)(C)CCC4(C)C)cc1] 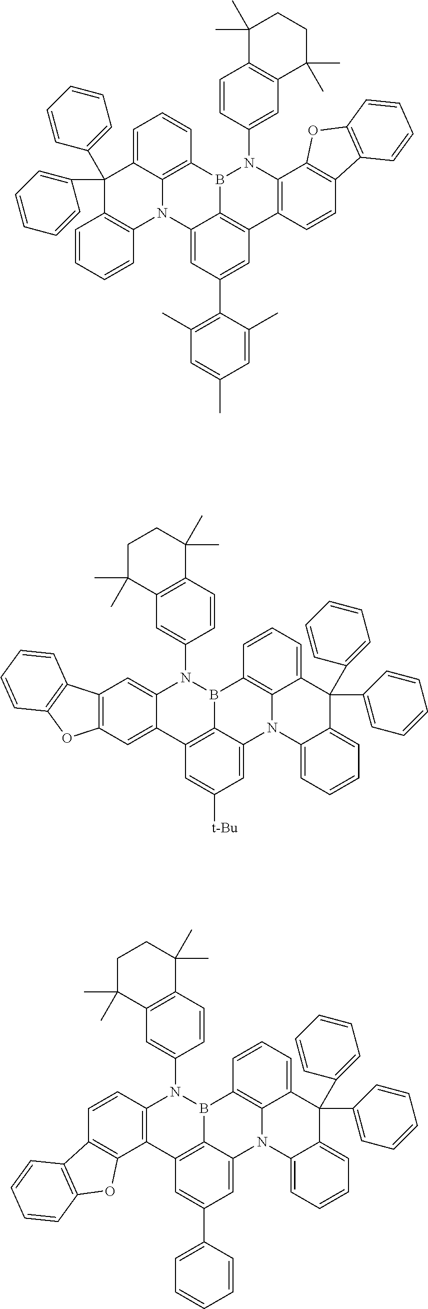 [SMILES: Cc1cc(C)c(-c2cc3c4c(c2)N2c5ccccc5C(c5ccccc5)(c5ccccc5)c5cccc(c52)B4N(c2ccc4c(c2)C(C)(C)CCC4(C)C)c2c-3ccc3c2oc2ccccc23)c(C)c1 ; CC(C)(C)c1cc2c3c(c1)N1c4ccccc4C(c4ccccc4)(c4ccccc4)c4cccc(c41)B3N(c1ccc3c(c1)C(C)(C)CCC3(C)C)c1cc3c(cc1-2)oc1ccccc13 ; CC1(C)CCC(C)(C)c2cc(N3B4c5cccc6c5N(c5ccccc5C6(c5ccccc5)c5ccccc5)c5cc(-c6ccccc6)cc(c54)-c4c3ccc3c4oc4ccccc43)ccc21] 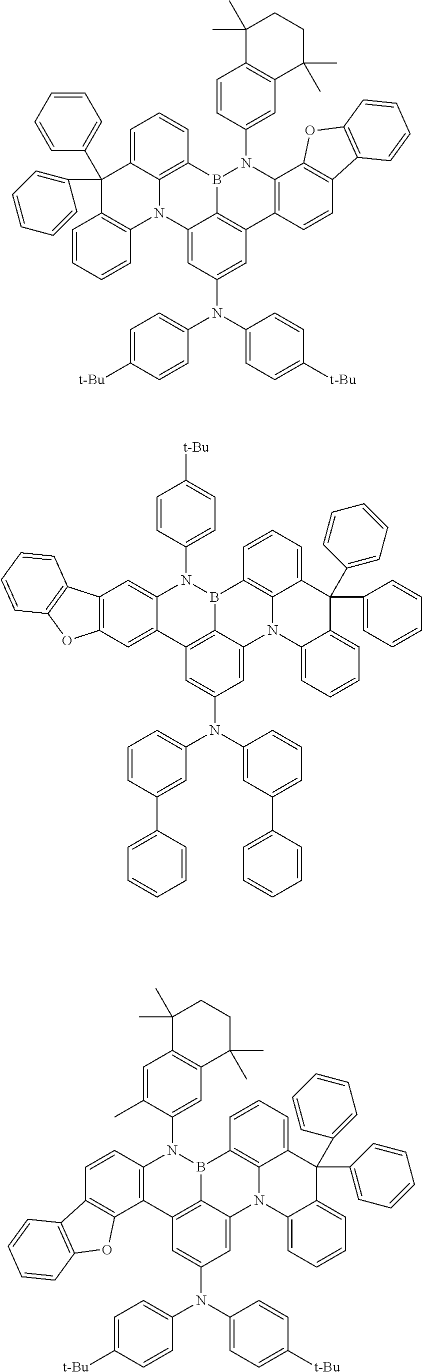 [SMILES: CC(C)(C)c1ccc(N(c2ccc(C(C)(C)C)cc2)c2cc3c4c(c2)N2c5ccccc5C(c5ccccc5)(c5ccccc5)c5cccc(c52)B4N(c2ccc4c(c2)C(C)(C)CCC4(C)C)c2c-3ccc3c2oc2ccccc23)cc1 ; CC(C)(C)c1ccc(N2B3c4cccc5c4N(c4ccccc4C5(c4ccccc4)c4ccccc4)c4cc(N(c5cccc(-c6ccccc6)c5)c5cccc(-c6ccccc6)c5)cc(c43)-c3cc4oc5ccccc5c4cc32)cc1 ; Cc1cc2c(cc1N1B3c4cccc5c4N(c4ccccc4C5(c4ccccc4)c4ccccc4)c4cc(N(c5ccc(C(C)(C)C)cc5)c5ccc(C(C)(C)C)cc5)cc(c43)-c3c1ccc1c3oc3ccccc31)C(C)(C)CCC2(C)C] 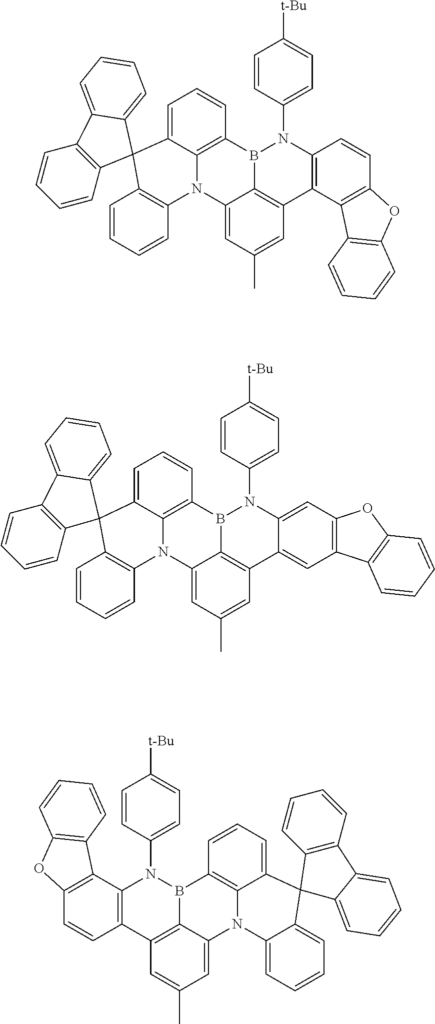 [SMILES: Cc1cc2c3c(c1)N1c4ccccc4C4(c5ccccc5-c5ccccc54)c4cccc(c41)B3N(c1ccc(C(C)(C)C)cc1)c1ccc3oc4ccccc4c3c1-2 ; Cc1cc2c3c(c1)N1c4ccccc4C4(c5ccccc5-c5ccccc54)c4cccc(c41)B3N(c1ccc(C(C)(C)C)cc1)c1cc3oc4ccccc4c3cc1-2 ; Cc1cc2c3c(c1)N1c4ccccc4C4(c5ccccc5-c5ccccc54)c4cccc(c41)B3N(c1ccc(C(C)(C)C)cc1)c1c-2ccc2oc3ccccc3c12] 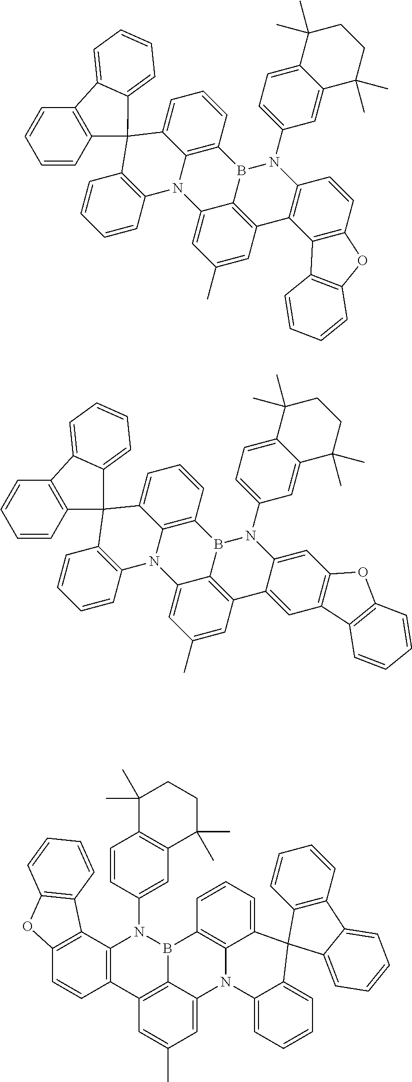 [SMILES: Cc1cc2c3c(c1)N1c4ccccc4C4(c5ccccc5-c5ccccc54)c4cccc(c41)B3N(c1ccc3c(c1)C(C)(C)CCC3(C)C)c1ccc3oc4ccccc4c3c1-2 ; Cc1cc2c3c(c1)N1c4ccccc4C4(c5ccccc5-c5ccccc54)c4cccc(c41)B3N(c1ccc3c(c1)C(C)(C)CCC3(C)C)c1cc3oc4ccccc4c3cc1-2 ; Cc1cc2c3c(c1)N1c4ccccc4C4(c5ccccc5-c5ccccc54)c4cccc(c41)B3N(c1ccc3c(c1)C(C)(C)CCC3(C)C)c1c-2ccc2oc3ccccc3c12] 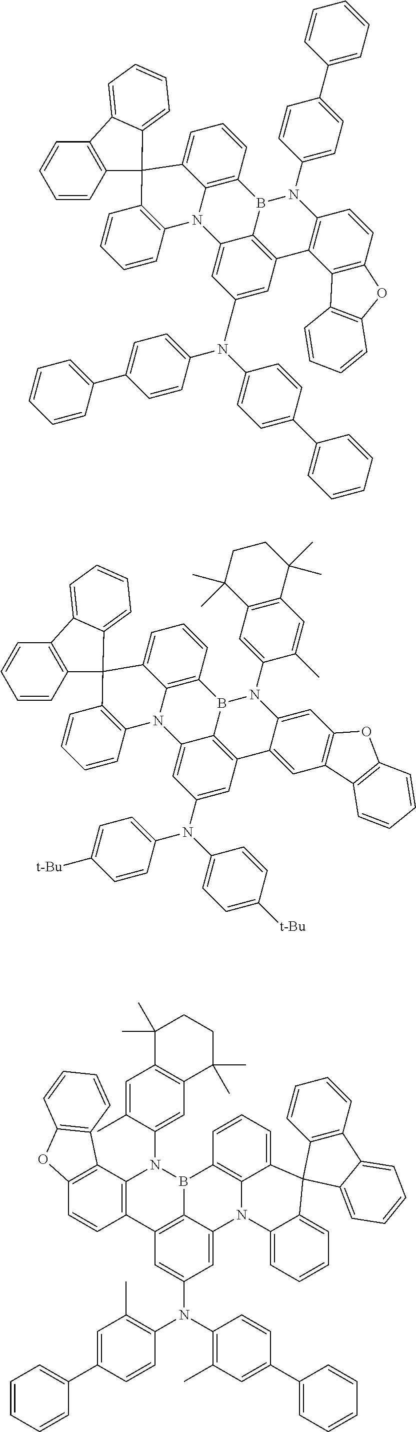 [SMILES: c1ccc(-c2ccc(N3B4c5cccc6c5N(c5ccccc5C65c6ccccc6-c6ccccc65)c5cc(N(c6ccc(-c7ccccc7)cc6)c6ccc(-c7ccccc7)cc6)cc(c54)-c4c3ccc3oc5ccccc5c43)cc2)cc1 ; Cc1cc2c(cc1N1B3c4cccc5c4N(c4ccccc4C54c5ccccc5-c5ccccc54)c4cc(N(c5ccc(C(C)(C)C)cc5)c5ccc(C(C)(C)C)cc5)cc(c43)-c3cc4c(cc31)oc1ccccc14)C(C)(C)CCC2(C)C ; Cc1cc2c(cc1N1B3c4cccc5c4N(c4ccccc4C54c5ccccc5-c5ccccc54)c4cc(N(c5ccc(-c6ccccc6)cc5C)c5ccc(-c6ccccc6)cc5C)cc(c43)-c3ccc4oc5ccccc5c4c31)C(C)(C)CCC2(C)C] 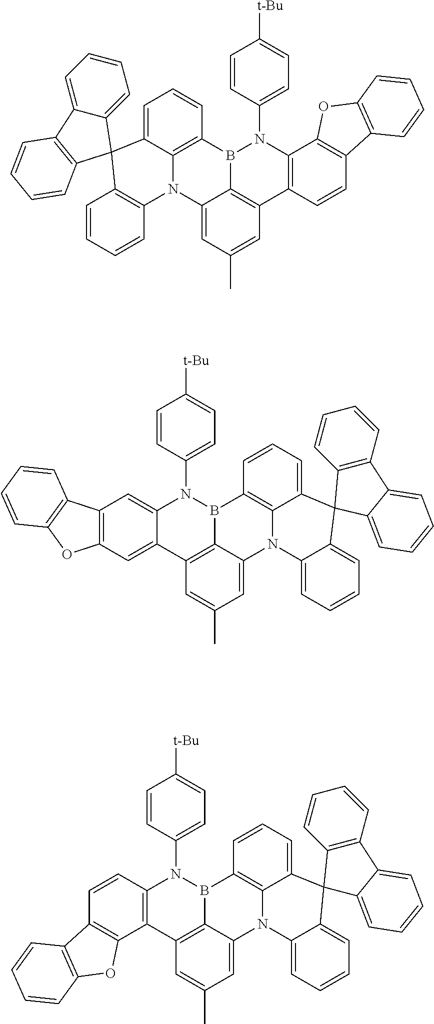 [SMILES: Cc1cc2c3c(c1)N1c4ccccc4C4(c5ccccc5-c5ccccc54)c4cccc(c41)B3N(c1ccc(C(C)(C)C)cc1)c1c-2ccc2c1oc1ccccc12 ; Cc1cc2c3c(c1)N1c4ccccc4C4(c5ccccc5-c5ccccc54)c4cccc(c41)B3N(c1ccc(C(C)(C)C)cc1)c1cc3c(cc1-2)oc1ccccc13 ; Cc1cc2c3c(c1)N1c4ccccc4C4(c5ccccc5-c5ccccc54)c4cccc(c41)B3N(c1ccc(C(C)(C)C)cc1)c1ccc3c(oc4ccccc43)c1-2] 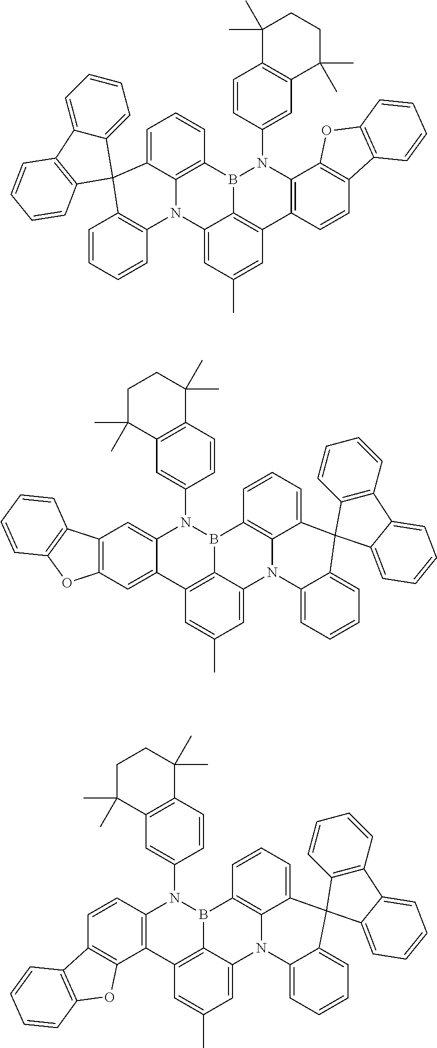 [SMILES: Cc1cc2c3c(c1)N1c4ccccc4C4(c5ccccc5-c5ccccc54)c4cccc(c41)B3N(c1ccc3c(c1)C(C)(C)CCC3(C)C)c1c-2ccc2c1oc1ccccc12 ; Cc1cc2c3c(c1)N1c4ccccc4C4(c5ccccc5-c5ccccc54)c4cccc(c41)B3N(c1ccc3c(c1)C(C)(C)CCC3(C)C)c1cc3c(cc1-2)oc1ccccc13 ; Cc1cc2c3c(c1)N1c4ccccc4C4(c5ccccc5-c5ccccc54)c4cccc(c41)B3N(c1ccc3c(c1)C(C)(C)CCC3(C)C)c1ccc3c(oc4ccccc43)c1-2] 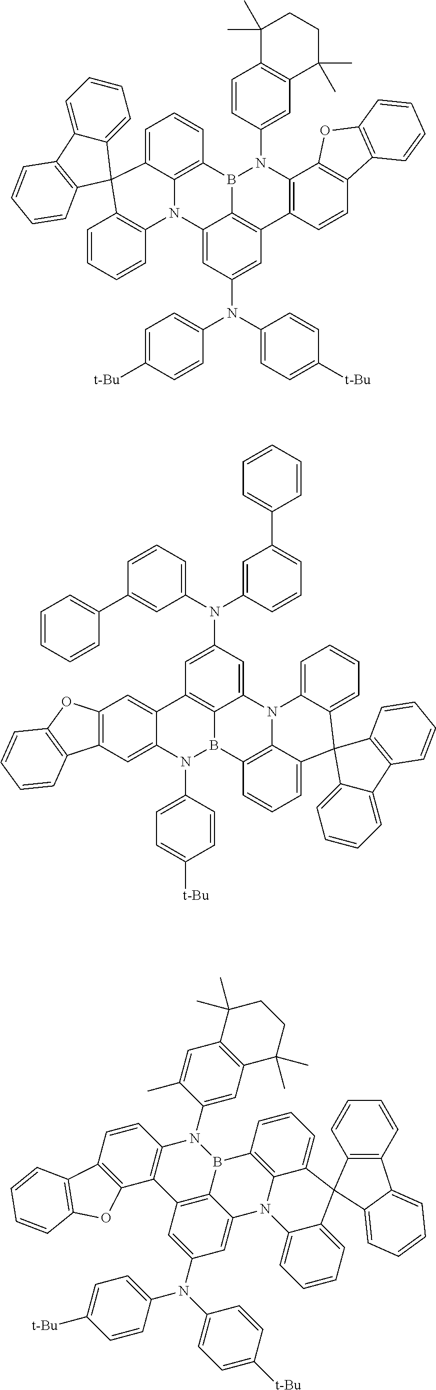 [SMILES: CC(C)(C)c1ccc(N(c2ccc(C(C)(C)C)cc2)c2cc3c4c(c2)N2c5ccccc5C5(c6ccccc6-c6ccccc65)c5cccc(c52)B4N(c2ccc4c(c2)C(C)(C)CCC4(C)C)c2c-3ccc3c2oc2ccccc23)cc1 ; CC(C)(C)c1ccc(N2B3c4cccc5c4N(c4ccccc4C54c5ccccc5-c5ccccc54)c4cc(N(c5cccc(-c6ccccc6)c5)c5cccc(-c6ccccc6)c5)cc(c43)-c3cc4oc5ccccc5c4cc32)cc1 ; Cc1cc2c(cc1N1B3c4cccc5c4N(c4ccccc4C54c5ccccc5-c5ccccc54)c4cc(N(c5ccc(C(C)(C)C)cc5)c5ccc(C(C)(C)C)cc5)cc(c43)-c3c1ccc1c3oc3ccccc31)C(C)(C)CCC2(C)C] 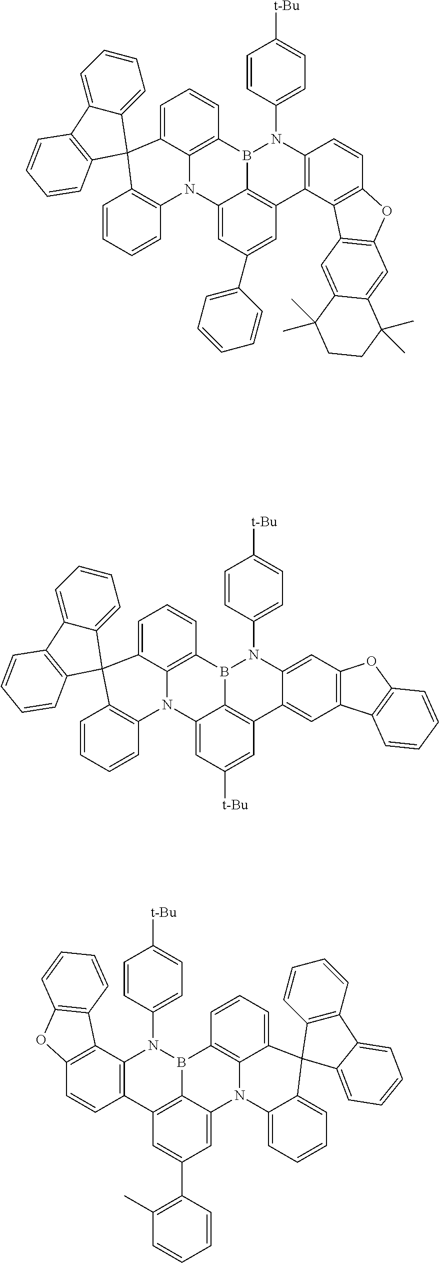 [SMILES: CC(C)(C)c1ccc(N2B3c4cccc5c4N(c4ccccc4C54c5ccccc5-c5ccccc54)c4cc(-c5ccccc5)cc(c43)-c3c2ccc2oc4cc5c(cc4c32)C(C)(C)CCC5(C)C)cc1 ; CC(C)(C)c1ccc(N2B3c4cccc5c4N(c4ccccc4C54c5ccccc5-c5ccccc54)c4cc(C(C)(C)C)cc(c43)-c3cc4c(cc32)oc2ccccc24)cc1 ; Cc1ccccc1-c1cc2c3c(c1)N1c4ccccc4C4(c5ccccc5-c5ccccc54)c4cccc(c41)B3N(c1ccc(C(C)(C)C)cc1)c1c-2ccc2oc3ccccc3c12] 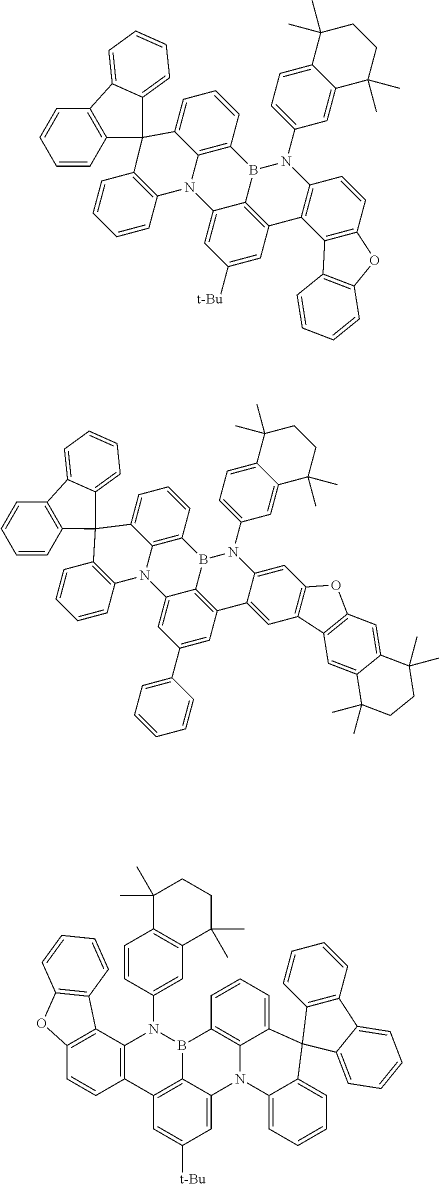 [SMILES: CC(C)(C)c1cc2c3c(c1)N1c4ccccc4C4(c5ccccc5-c5ccccc54)c4cccc(c41)B3N(c1ccc3c(c1)C(C)(C)CCC3(C)C)c1ccc3oc4ccccc4c3c1-2 ; CC1(C)CCC(C)(C)c2cc(N3B4c5cccc6c5N(c5ccccc5C65c6ccccc6-c6ccccc65)c5cc(-c6ccccc6)cc(c54)-c4cc5c(cc43)oc3cc4c(cc35)C(C)(C)CCC4(C)C)ccc21 ; CC(C)(C)c1cc2c3c(c1)N1c4ccccc4C4(c5ccccc5-c5ccccc54)c4cccc(c41)B3N(c1ccc3c(c1)C(C)(C)CCC3(C)C)c1c-2ccc2oc3ccccc3c12] 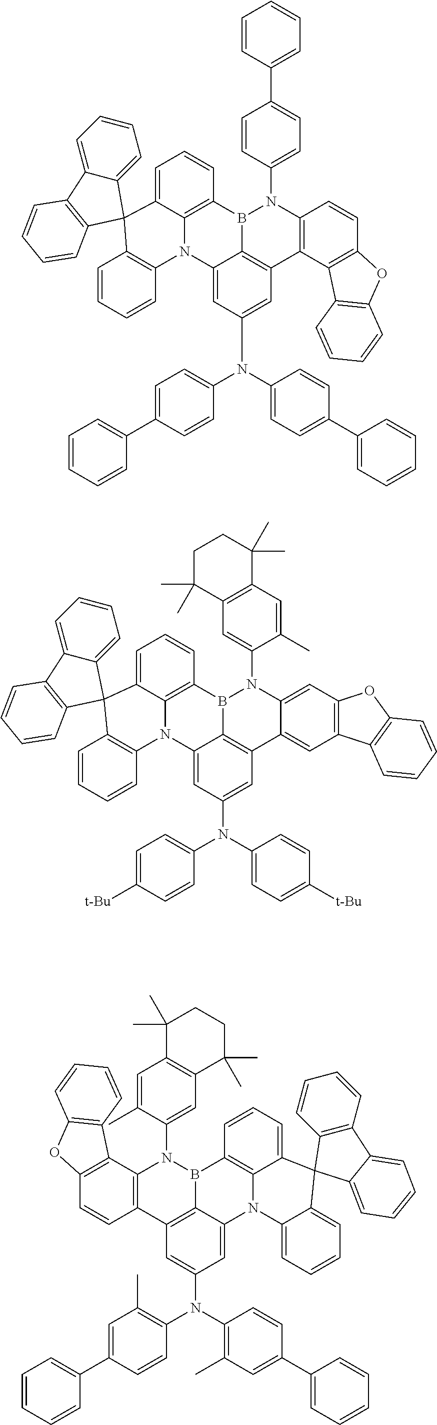 [SMILES: c1ccc(-c2ccc(N3B4c5cccc6c5N(c5ccccc5C65c6ccccc6-c6ccccc65)c5cc(N(c6ccc(-c7ccccc7)cc6)c6ccc(-c7ccccc7)cc6)cc(c54)-c4c3ccc3oc5ccccc5c43)cc2)cc1 ; Cc1cc2c(cc1N1B3c4cccc5c4N(c4ccccc4C54c5ccccc5-c5ccccc54)c4cc(N(c5ccc(C(C)(C)C)cc5)c5ccc(C(C)(C)C)cc5)cc(c43)-c3cc4c(cc31)oc1ccccc14)C(C)(C)CCC2(C)C ; Cc1cc2c(cc1N1B3c4cccc5c4N(c4ccccc4C54c5ccccc5-c5ccccc54)c4cc(N(c5ccc(-c6ccccc6)cc5C)c5ccc(-c6ccccc6)cc5C)cc(c43)-c3ccc4oc5ccccc5c4c31)C(C)(C)CCC2(C)C] 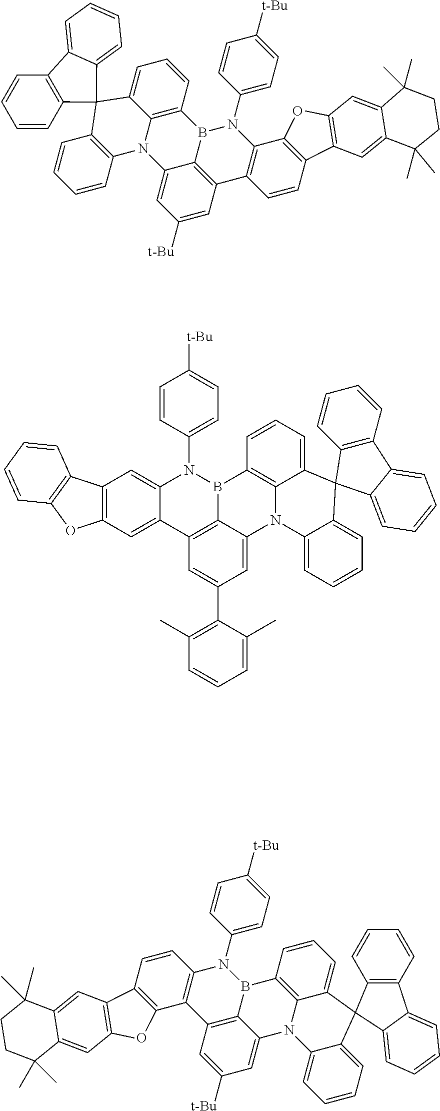 [SMILES: CC(C)(C)c1ccc(N2B3c4cccc5c4N(c4ccccc4C54c5ccccc5-c5ccccc54)c4cc(C(C)(C)C)cc(c43)-c3ccc4c(oc5cc6c(cc54)C(C)(C)CCC6(C)C)c32)cc1 ; Cc1cccc(C)c1-c1cc2c3c(c1)N1c4ccccc4C4(c5ccccc5-c5ccccc54)c4cccc(c41)B3N(c1ccc(C(C)(C)C)cc1)c1cc3c(cc1-2)oc1ccccc13 ; CC(C)(C)c1ccc(N2B3c4cccc5c4N(c4ccccc4C54c5ccccc5-c5ccccc54)c4cc(C(C)(C)C)cc(c43)-c3c2ccc2c3oc3cc4c(cc32)C(C)(C)CCC4(C)C)cc1] 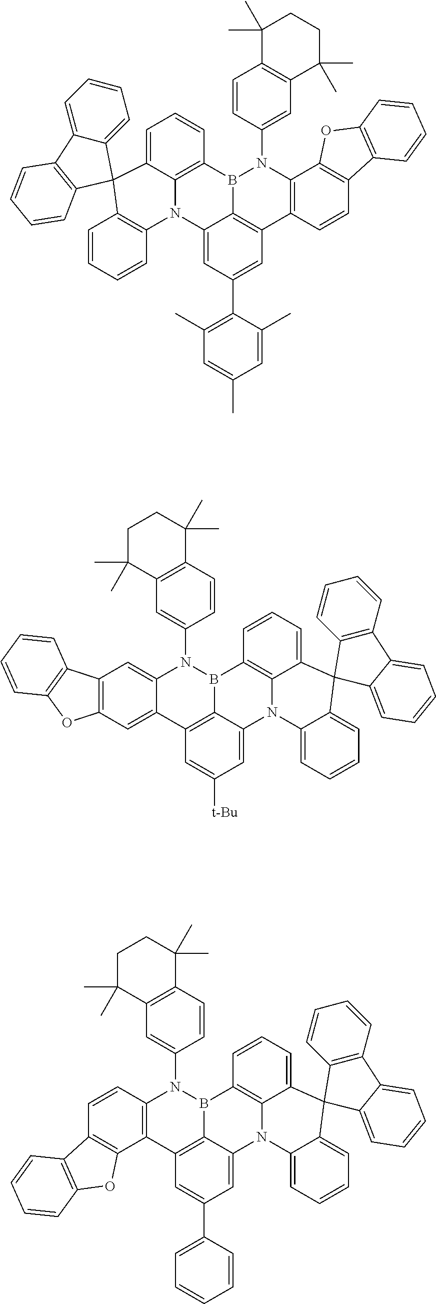 [SMILES: Cc1cc(C)c(-c2cc3c4c(c2)N2c5ccccc5C5(c6ccccc6-c6ccccc65)c5cccc(c52)B4N(c2ccc4c(c2)C(C)(C)CCC4(C)C)c2c-3ccc3c2oc2ccccc23)c(C)c1 ; CC(C)(C)c1cc2c3c(c1)N1c4ccccc4C4(c5ccccc5-c5ccccc54)c4cccc(c41)B3N(c1ccc3c(c1)C(C)(C)CCC3(C)C)c1cc3c(cc1-2)oc1ccccc13 ; CC1(C)CCC(C)(C)c2cc(N3B4c5cccc6c5N(c5ccccc5C65c6ccccc6-c6ccccc65)c5cc(-c6ccccc6)cc(c54)-c4c3ccc3c4oc4ccccc43)ccc21] 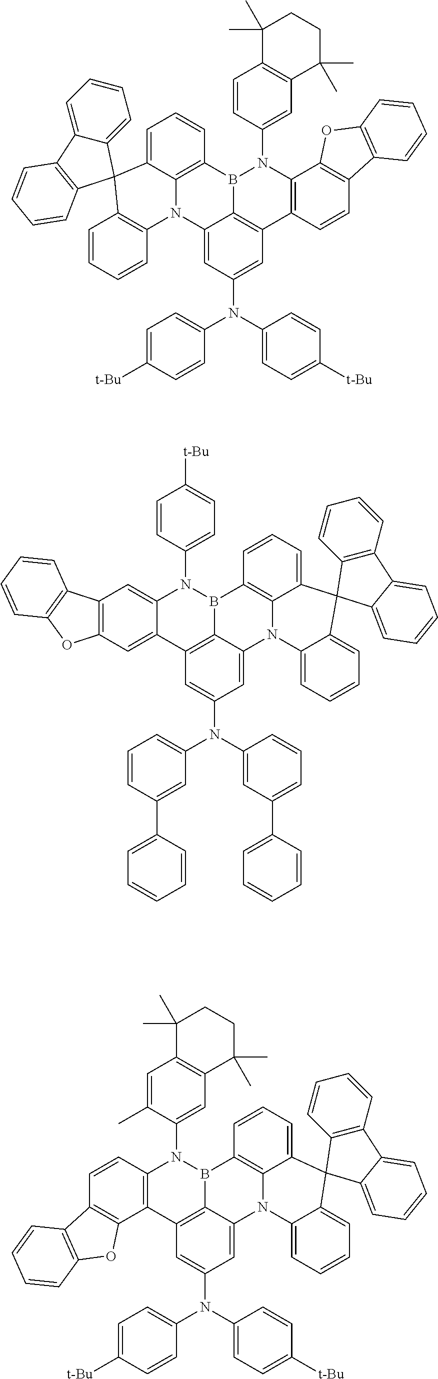 [SMILES: CC(C)(C)c1ccc(N(c2ccc(C(C)(C)C)cc2)c2cc3c4c(c2)N2c5ccccc5C5(c6ccccc6-c6ccccc65)c5cccc(c52)B4N(c2ccc4c(c2)C(C)(C)CCC4(C)C)c2c-3ccc3c2oc2ccccc23)cc1 ; CC(C)(C)c1ccc(N2B3c4cccc5c4N(c4ccccc4C54c5ccccc5-c5ccccc54)c4cc(N(c5cccc(-c6ccccc6)c5)c5cccc(-c6ccccc6)c5)cc(c43)-c3cc4oc5ccccc5c4cc32)cc1 ; Cc1cc2c(cc1N1B3c4cccc5c4N(c4ccccc4C54c5ccccc5-c5ccccc54)c4cc(N(c5ccc(C(C)(C)C)cc5)c5ccc(C(C)(C)C)cc5)cc(c43)-c3c1ccc1c3oc3ccccc31)C(C)(C)CCC2(C)C] 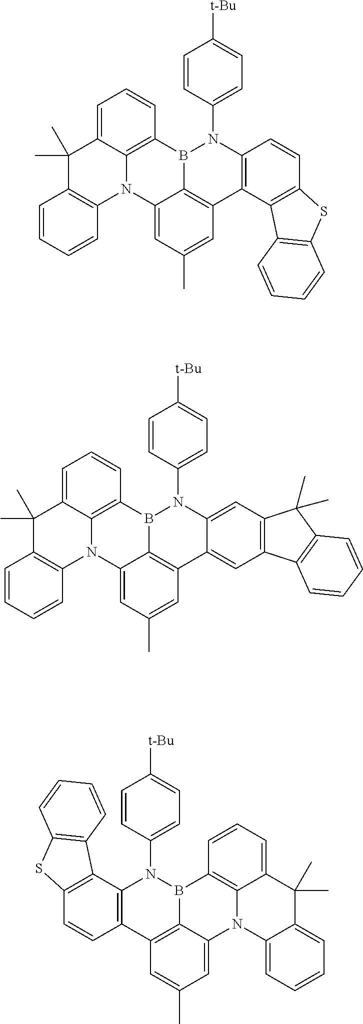 [SMILES: Cc1cc2c3c(c1)N1c4ccccc4C(C)(C)c4cccc(c41)B3N(c1ccc(C(C)(C)C)cc1)c1ccc3sc4ccccc4c3c1-2 ; Cc1cc2c3c(c1)N1c4ccccc4C(C)(C)c4cccc(c41)B3N(c1ccc(C(C)(C)C)cc1)c1cc3c(cc1-2)-c1ccccc1C3(C)C ; Cc1cc2c3c(c1)N1c4ccccc4C(C)(C)c4cccc(c41)B3N(c1ccc(C(C)(C)C)cc1)c1c-2ccc2sc3ccccc3c12] 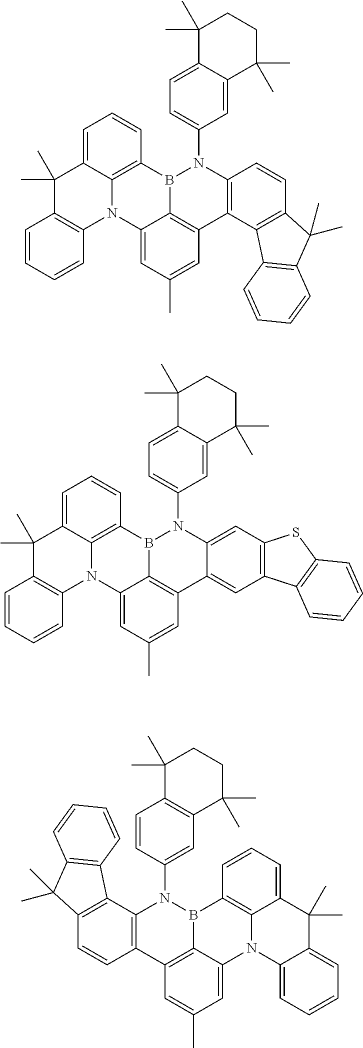 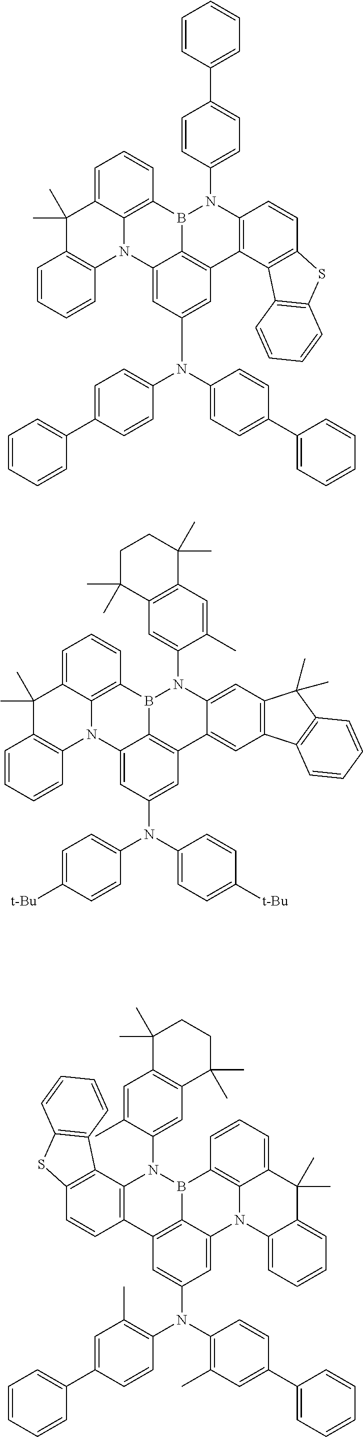 [SMILES: CC1(C)c2ccccc2N2c3cc(N(c4ccc(-c5ccccc5)cc4)c4ccc(-c5ccccc5)cc4)cc4c3B(c3cccc1c32)N(c1ccc(-c2ccccc2)cc1)c1ccc2sc3ccccc3c2c1-4 ; Cc1cc2c(cc1N1B3c4cccc5c4N(c4ccccc4C5(C)C)c4cc(N(c5ccc(C(C)(C)C)cc5)c5ccc(C(C)(C)C)cc5)cc(c43)-c3cc4c(cc31)C(C)(C)c1ccccc1-4)C(C)(C)CCC2(C)C ; Cc1cc2c(cc1N1B3c4cccc5c4N(c4ccccc4C5(C)C)c4cc(N(c5ccc(-c6ccccc6)cc5C)c5ccc(-c6ccccc6)cc5C)cc(c43)-c3ccc4sc5ccccc5c4c31)C(C)(C)CCC2(C)C] 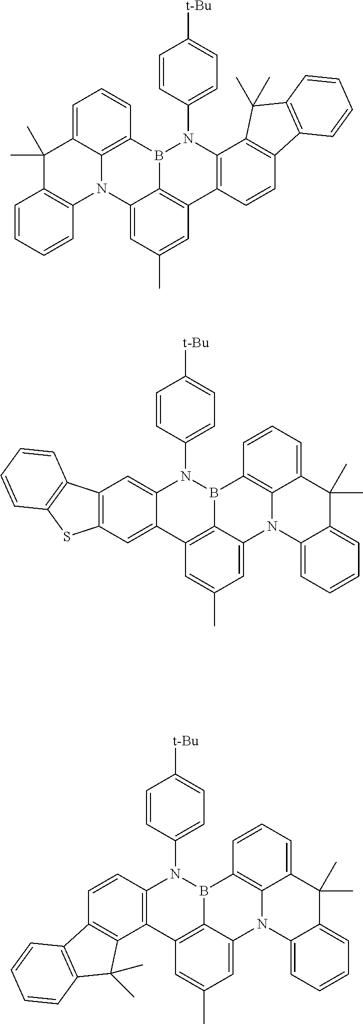 [SMILES: Cc1cc2c3c(c1)N1c4ccccc4C(C)(C)c4cccc(c41)B3N(c1ccc(C(C)(C)C)cc1)c1c-2ccc2c1C(C)(C)c1ccccc1-2 ; Cc1cc2c3c(c1)N1c4ccccc4C(C)(C)c4cccc(c41)B3N(c1ccc(C(C)(C)C)cc1)c1cc3c(cc1-2)sc1ccccc13 ; Cc1cc2c3c(c1)N1c4ccccc4C(C)(C)c4cccc(c41)B3N(c1ccc(C(C)(C)C)cc1)c1ccc3c(c1-2)C(C)(C)c1ccccc1-3] 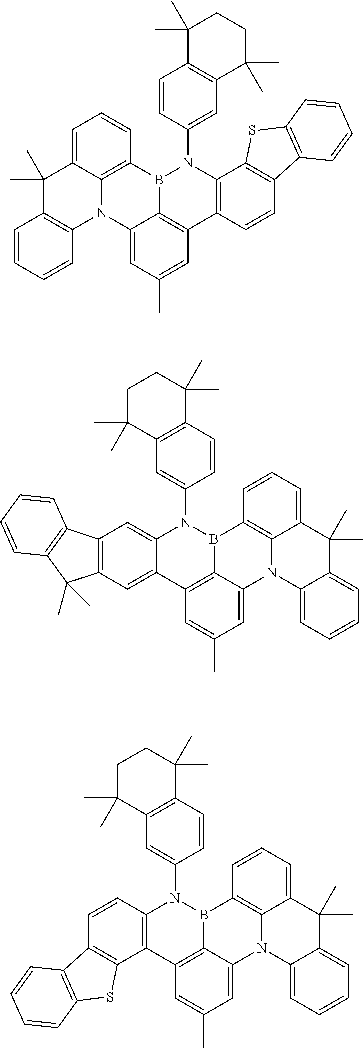 [SMILES: Cc1cc2c3c(c1)N1c4ccccc4C(C)(C)c4cccc(c41)B3N(c1ccc3c(c1)C(C)(C)CCC3(C)C)c1c-2ccc2c1sc1ccccc12 ; Cc1cc2c3c(c1)N1c4ccccc4C(C)(C)c4cccc(c41)B3N(c1ccc3c(c1)C(C)(C)CCC3(C)C)c1cc3c(cc1-2)C(C)(C)c1ccccc1-3 ; Cc1cc2c3c(c1)N1c4ccccc4C(C)(C)c4cccc(c41)B3N(c1ccc3c(c1)C(C)(C)CCC3(C)C)c1ccc3c(sc4ccccc43)c1-2] 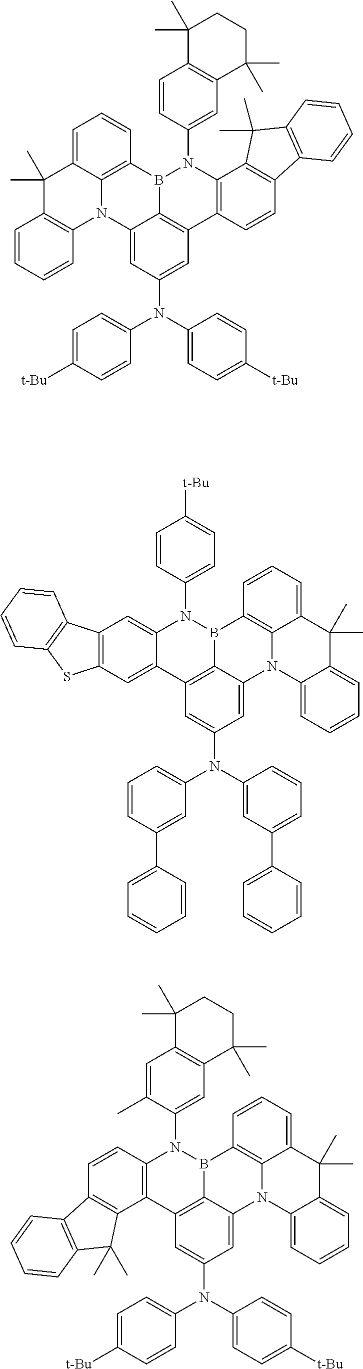 [SMILES: CC(C)(C)c1ccc(N(c2ccc(C(C)(C)C)cc2)c2cc3c4c(c2)N2c5ccccc5C(C)(C)c5cccc(c52)B4N(c2ccc4c(c2)C(C)(C)CCC4(C)C)c2c-3ccc3c2C(C)(C)c2ccccc2-3)cc1 ; CC(C)(C)c1ccc(N2B3c4cccc5c4N(c4ccccc4C5(C)C)c4cc(N(c5cccc(-c6ccccc6)c5)c5cccc(-c6ccccc6)c5)cc(c43)-c3cc4sc5ccccc5c4cc32)cc1 ; Cc1cc2c(cc1N1B3c4cccc5c4N(c4ccccc4C5(C)C)c4cc(N(c5ccc(C(C)(C)C)cc5)c5ccc(C(C)(C)C)cc5)cc(c43)-c3c1ccc1c3C(C)(C)c3ccccc3-1)C(C)(C)CCC2(C)C] 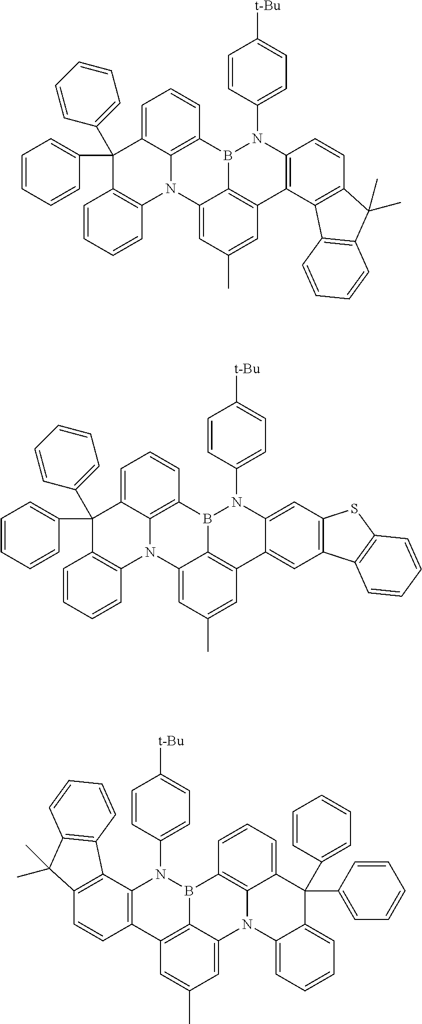 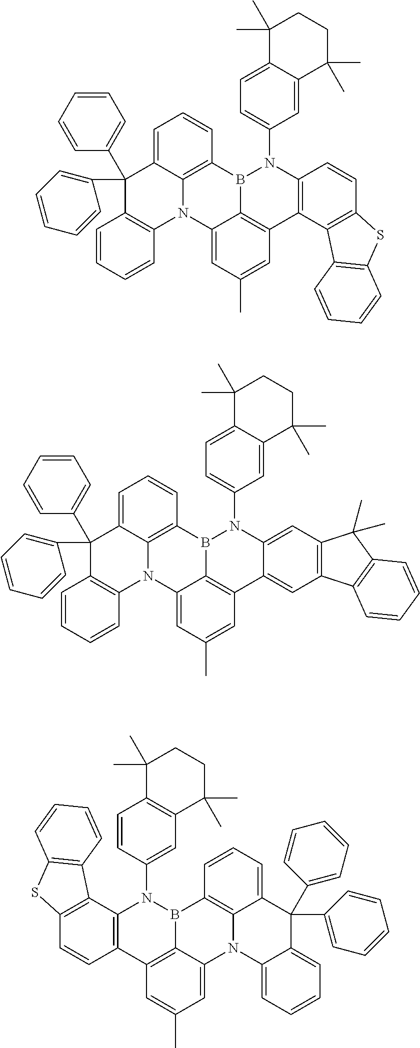 [SMILES: Cc1cc2c3c(c1)N1c4ccccc4C(c4ccccc4)(c4ccccc4)c4cccc(c41)B3N(c1ccc3c(c1)C(C)(C)CCC3(C)C)c1ccc3sc4ccccc4c3c1-2 ; Cc1cc2c3c(c1)N1c4ccccc4C(c4ccccc4)(c4ccccc4)c4cccc(c41)B3N(c1ccc3c(c1)C(C)(C)CCC3(C)C)c1cc3c(cc1-2)-c1ccccc1C3(C)C ; Cc1cc2c3c(c1)N1c4ccccc4C(c4ccccc4)(c4ccccc4)c4cccc(c41)B3N(c1ccc3c(c1)C(C)(C)CCC3(C)C)c1c-2ccc2sc3ccccc3c12] 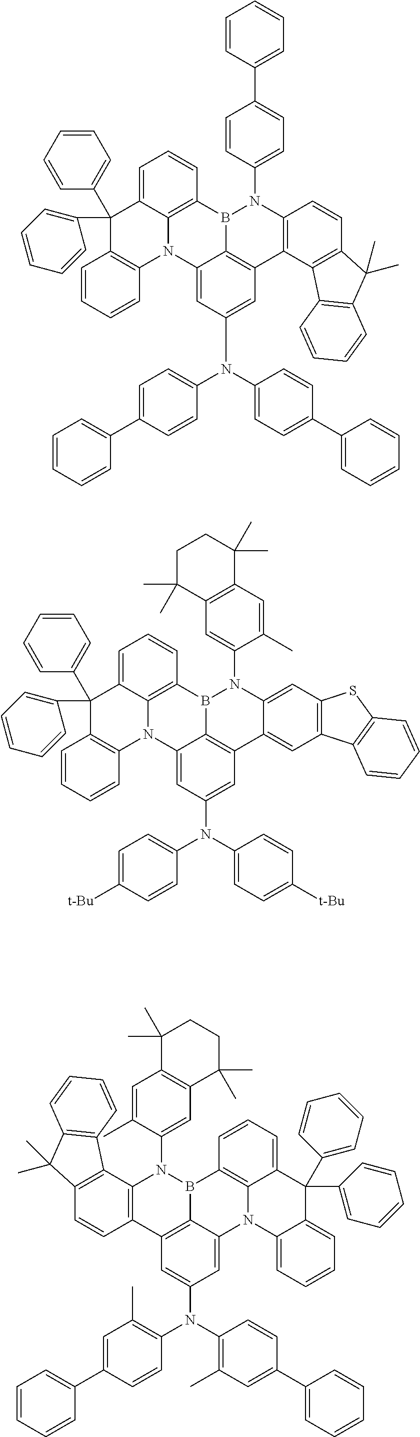 [SMILES: CC1(C)c2ccccc2-c2c1ccc1c2-c2cc(N(c3ccc(-c4ccccc4)cc3)c3ccc(-c4ccccc4)cc3)cc3c2B(c2cccc4c2N3c2ccccc2C4(c2ccccc2)c2ccccc2)N1c1ccc(-c2ccccc2)cc1 ; Cc1cc2c(cc1N1B3c4cccc5c4N(c4ccccc4C5(c4ccccc4)c4ccccc4)c4cc(N(c5ccc(C(C)(C)C)cc5)c5ccc(C(C)(C)C)cc5)cc(c43)-c3cc4c(cc31)sc1ccccc14)C(C)(C)CCC2(C)C ; Cc1cc2c(cc1N1B3c4cccc5c4N(c4ccccc4C5(c4ccccc4)c4ccccc4)c4cc(N(c5ccc(-c6ccccc6)cc5C)c5ccc(-c6ccccc6)cc5C)cc(c43)-c3ccc4c(c31)-c1ccccc1C4(C)C)C(C)(C)CCC2(C)C] 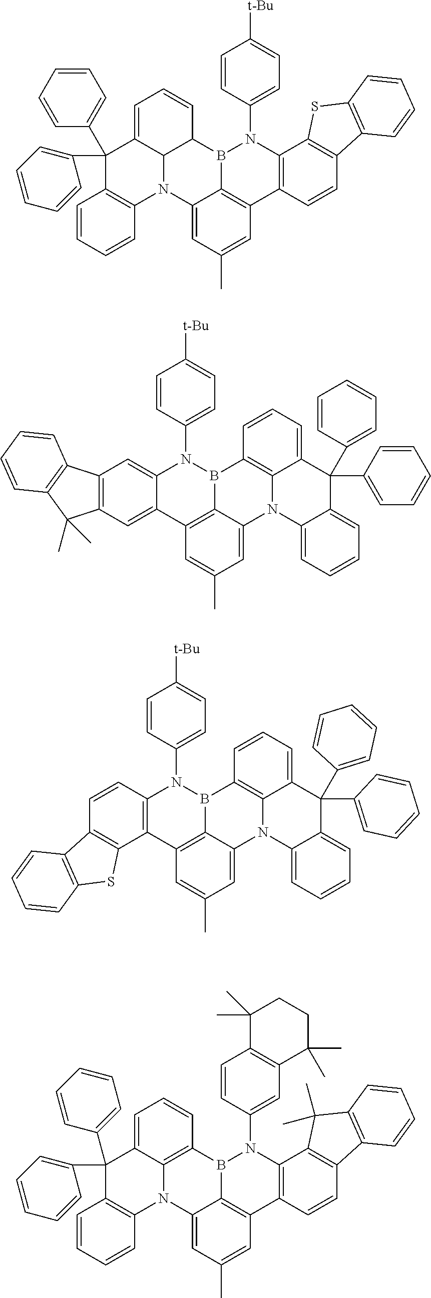 [SMILES: Cc1cc2c3c(c1)N1c4ccccc4C(c4ccccc4)(c4ccccc4)C4=CC=CC(B3N(c3ccc(C(C)(C)C)cc3)c3c-2ccc2c3sc3ccccc32)C41 ; Cc1cc2c3c(c1)N1c4ccccc4C(c4ccccc4)(c4ccccc4)c4cccc(c41)B3N(c1ccc(C(C)(C)C)cc1)c1cc3c(cc1-2)C(C)(C)c1ccccc1-3 ; Cc1cc2c3c(c1)N1c4ccccc4C(c4ccccc4)(c4ccccc4)c4cccc(c41)B3N(c1ccc(C(C)(C)C)cc1)c1ccc3c(sc4ccccc43)c1-2 ; Cc1cc2c3c(c1)N1c4ccccc4C(c4ccccc4)(c4ccccc4)c4cccc(c41)B3N(c1ccc3c(c1)C(C)(C)CCC3(C)C)c1c-2ccc2c1C(C)(C)c1ccccc1-2] 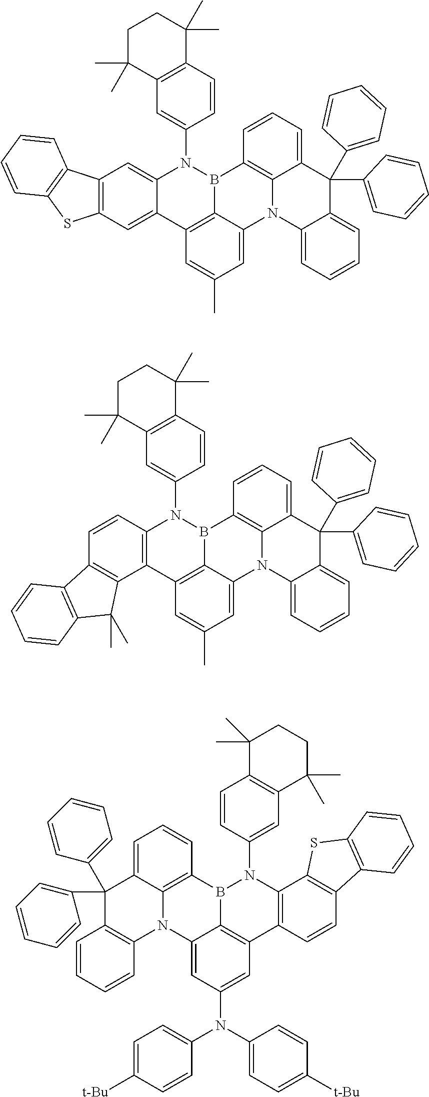 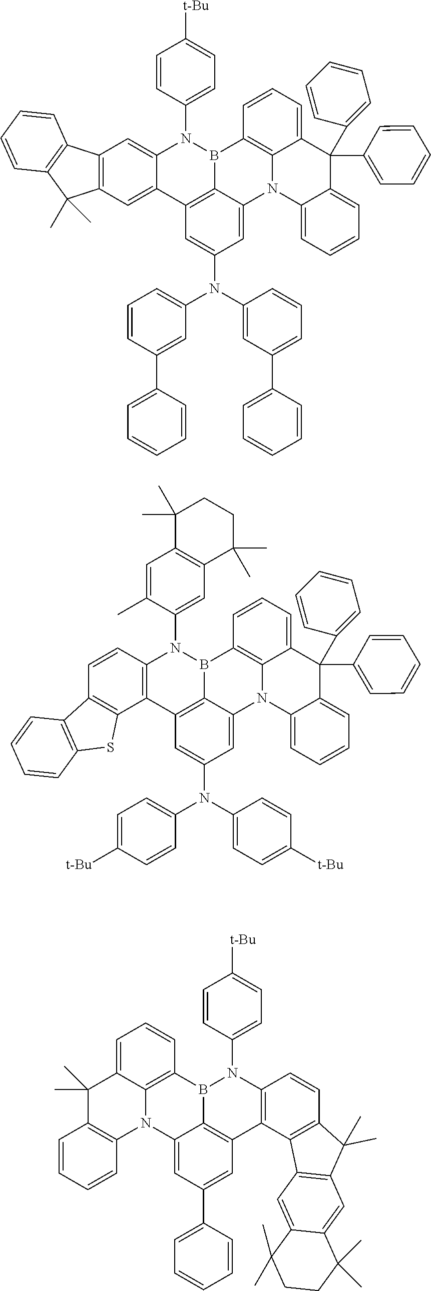 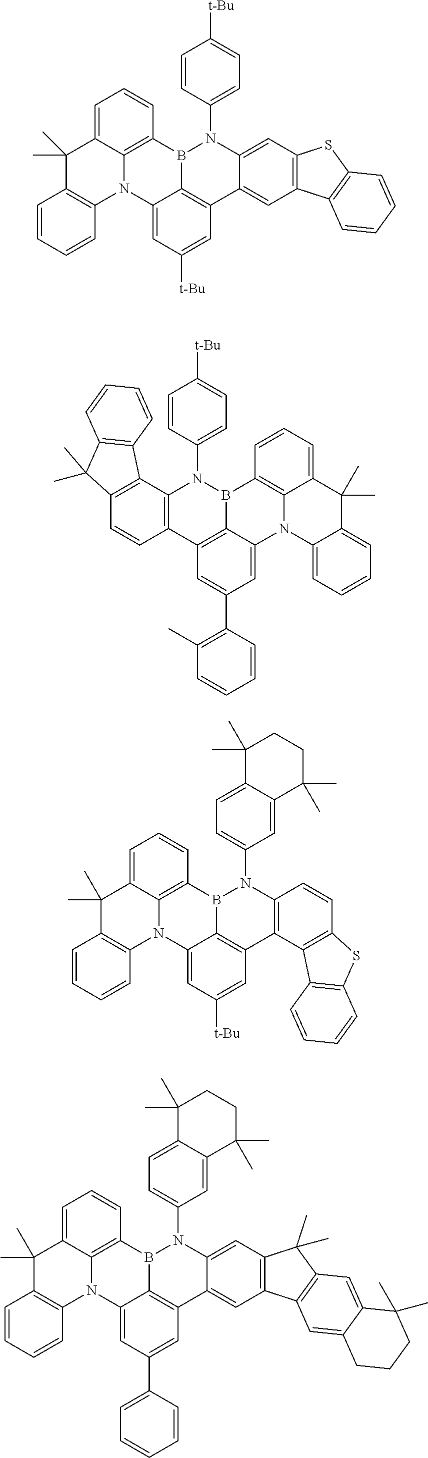 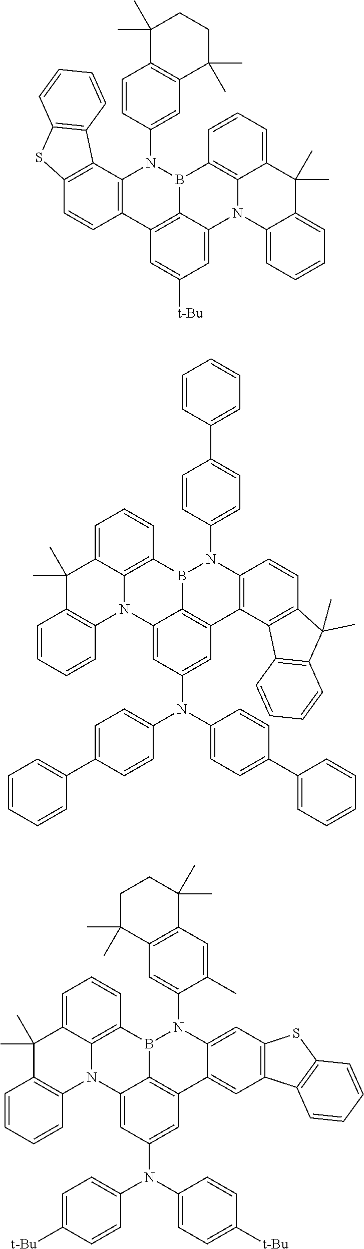 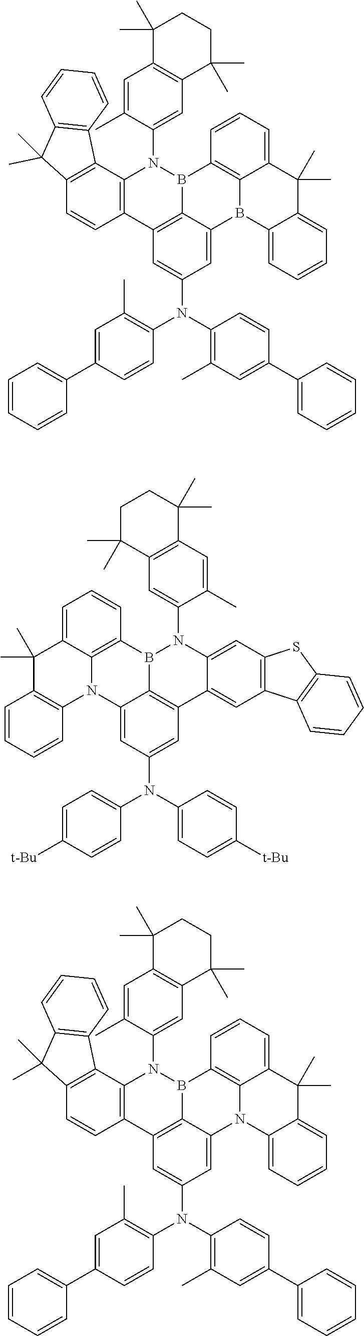 [SMILES: Cc1cc2c(cc1N1B3c4cccc5c4B(c4ccccc4C5(C)C)c4cc(N(c5ccc(-c6ccccc6)cc5C)c5ccc(-c6ccccc6)cc5C)cc(c43)-c3ccc4c(c31)-c1ccccc1C4(C)C)C(C)(C)CCC2(C)C ; Cc1cc2c(cc1N1B3c4cccc5c4N(c4ccccc4C5(C)C)c4cc(N(c5ccc(C(C)(C)C)cc5)c5ccc(C(C)(C)C)cc5)cc(c43)-c3cc4c(cc31)sc1ccccc14)C(C)(C)CCC2(C)C ; Cc1cc2c(cc1N1B3c4cccc5c4N(c4ccccc4C5(C)C)c4cc(N(c5ccc(-c6ccccc6)cc5C)c5ccc(-c6ccccc6)cc5C)cc(c43)-c3ccc4c(c31)-c1ccccc1C4(C)C)C(C)(C)CCC2(C)C] 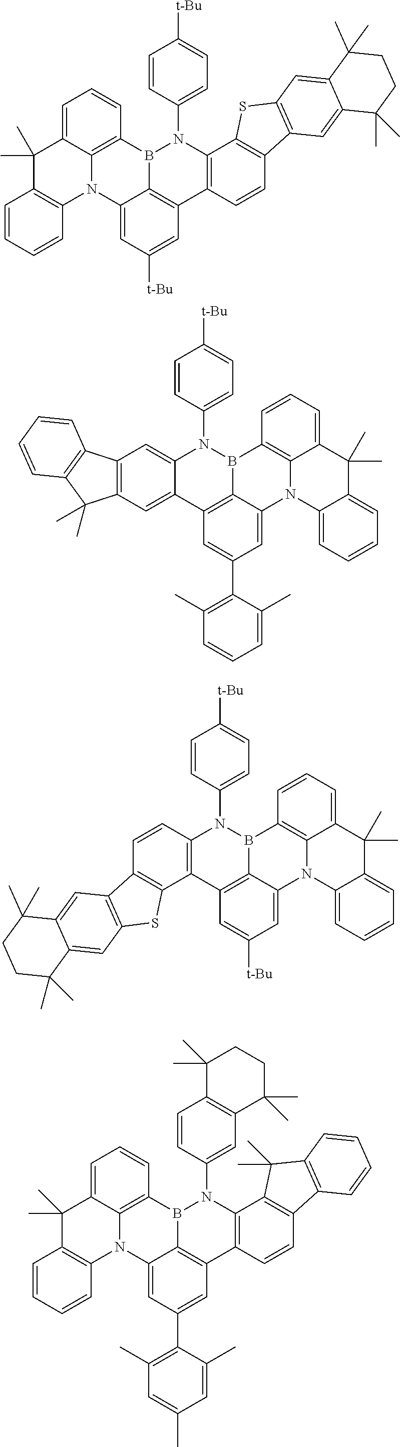 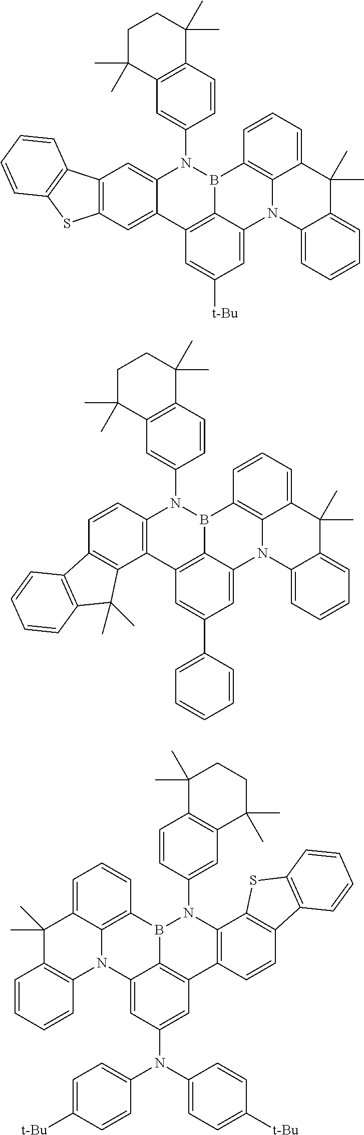 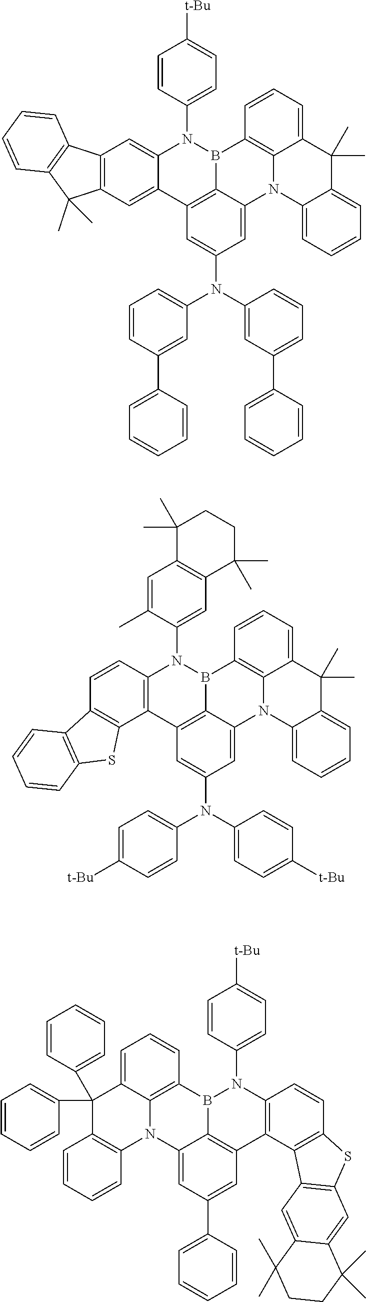 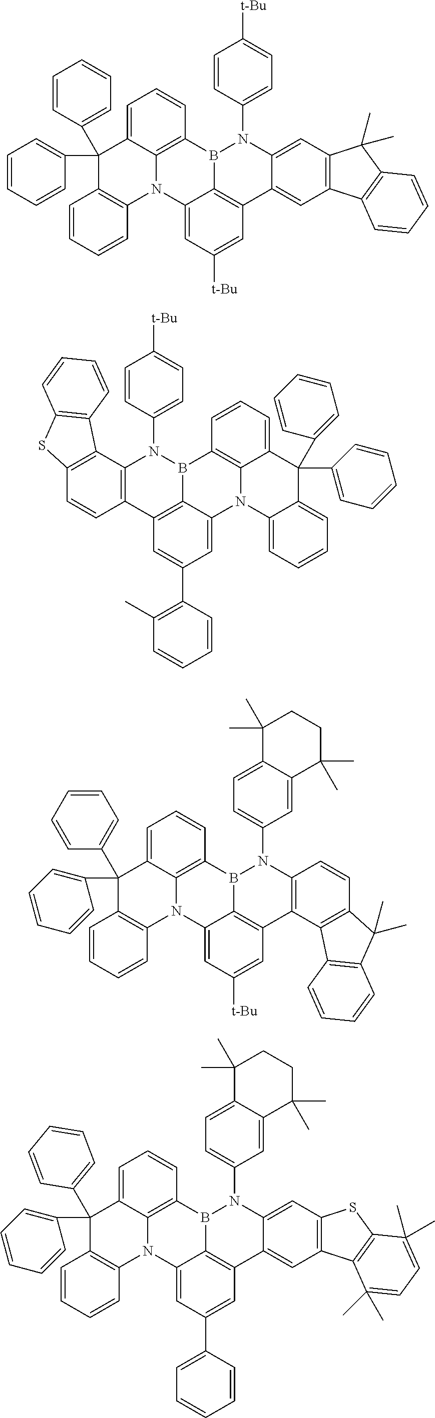 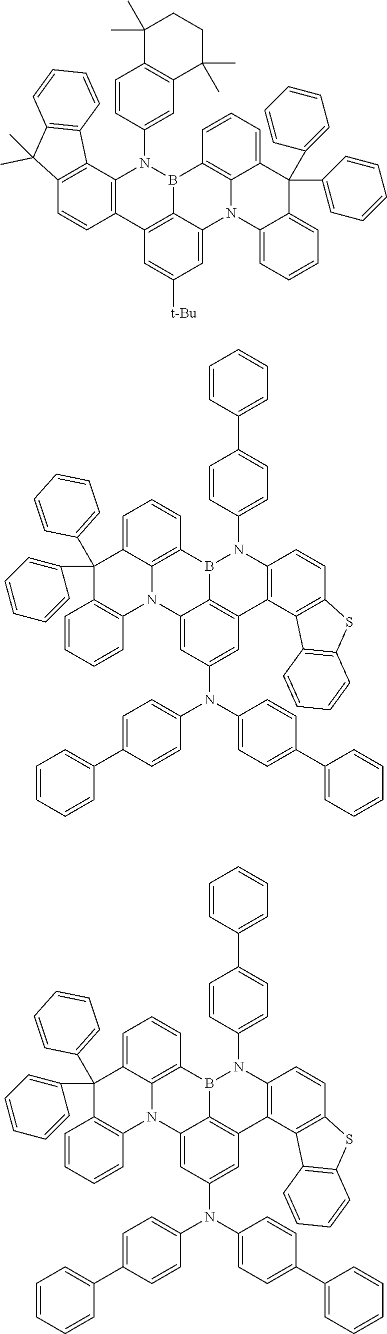 [SMILES: CC(C)(C)c1cc2c3c(c1)N1c4ccccc4C(c4ccccc4)(c4ccccc4)c4cccc(c41)B3N(c1ccc3c(c1)C(C)(C)CCC3(C)C)c1c-2ccc2c1-c1ccccc1C2(C)C ; c1ccc(-c2ccc(N3B4c5cccc6c5N(c5ccccc5C6(c5ccccc5)c5ccccc5)c5cc(N(c6ccc(-c7ccccc7)cc6)c6ccc(-c7ccccc7)cc6)cc(c54)-c4c3ccc3sc5ccccc5c43)cc2)cc1 ; c1ccc(-c2ccc(N3B4c5cccc6c5N(c5ccccc5C6(c5ccccc5)c5ccccc5)c5cc(N(c6ccc(-c7ccccc7)cc6)c6ccc(-c7ccccc7)cc6)cc(c54)-c4c3ccc3sc5ccccc5c43)cc2)cc1] 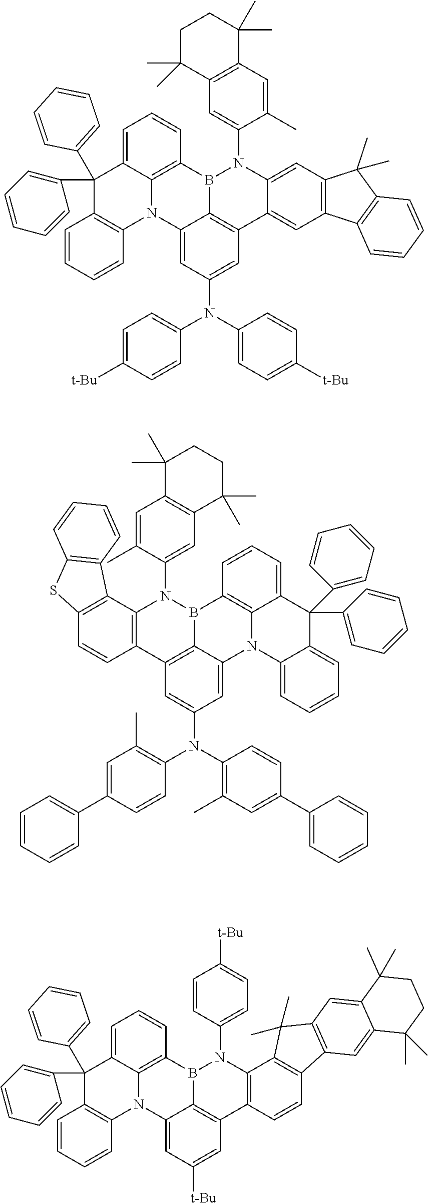 [SMILES: Cc1cc2c(cc1N1B3c4cccc5c4N(c4ccccc4C5(c4ccccc4)c4ccccc4)c4cc(N(c5ccc(C(C)(C)C)cc5)c5ccc(C(C)(C)C)cc5)cc(c43)-c3cc4c(cc31)C(C)(C)c1ccccc1-4)C(C)(C)CCC2(C)C ; Cc1cc2c(cc1N1B3c4cccc5c4N(c4ccccc4C5(c4ccccc4)c4ccccc4)c4cc(N(c5ccc(-c6ccccc6)cc5C)c5ccc(-c6ccccc6)cc5C)cc(c43)-c3ccc4sc5ccccc5c4c31)C(C)(C)CCC2(C)C ; CC(C)(C)c1ccc(N2B3c4cccc5c4N(c4ccccc4C5(c4ccccc4)c4ccccc4)c4cc(C(C)(C)C)cc(c43)-c3ccc4c(c32)C(C)(C)c2cc3c(cc2-4)C(C)(C)CCC3(C)C)cc1] 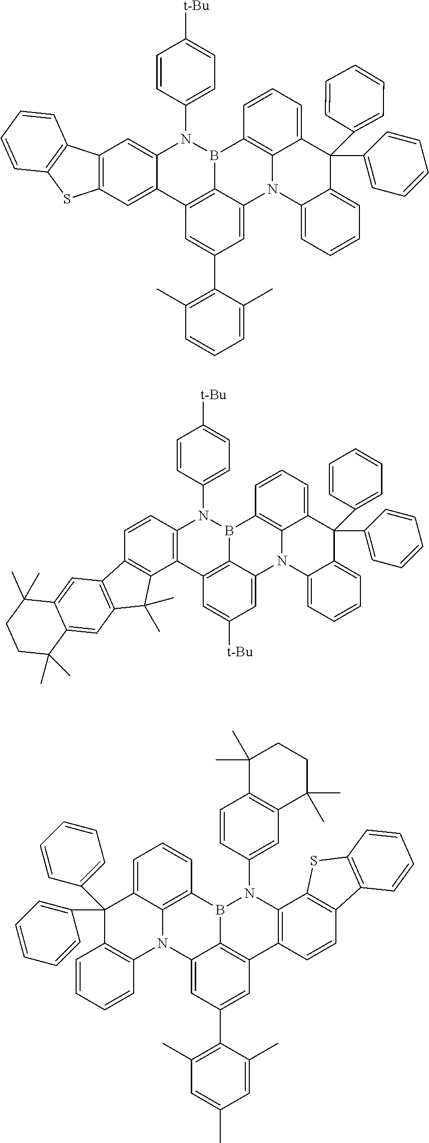 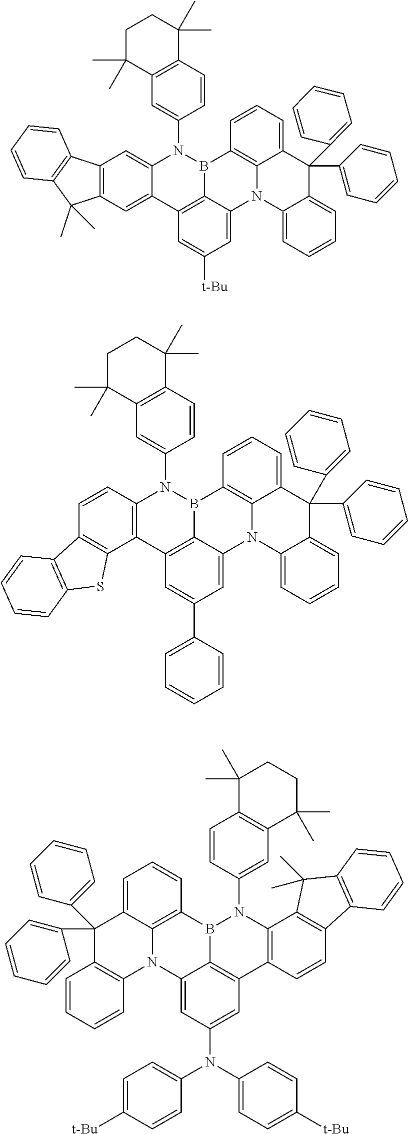 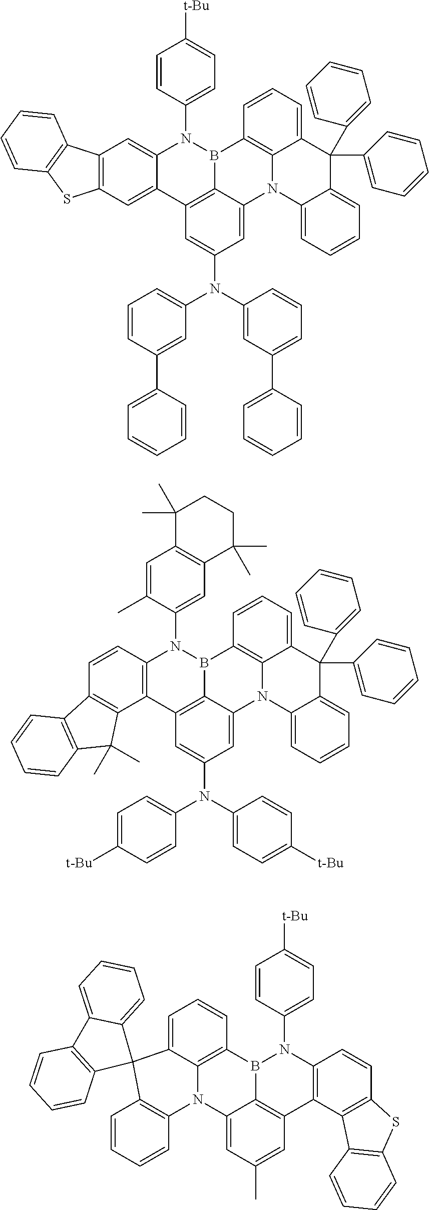 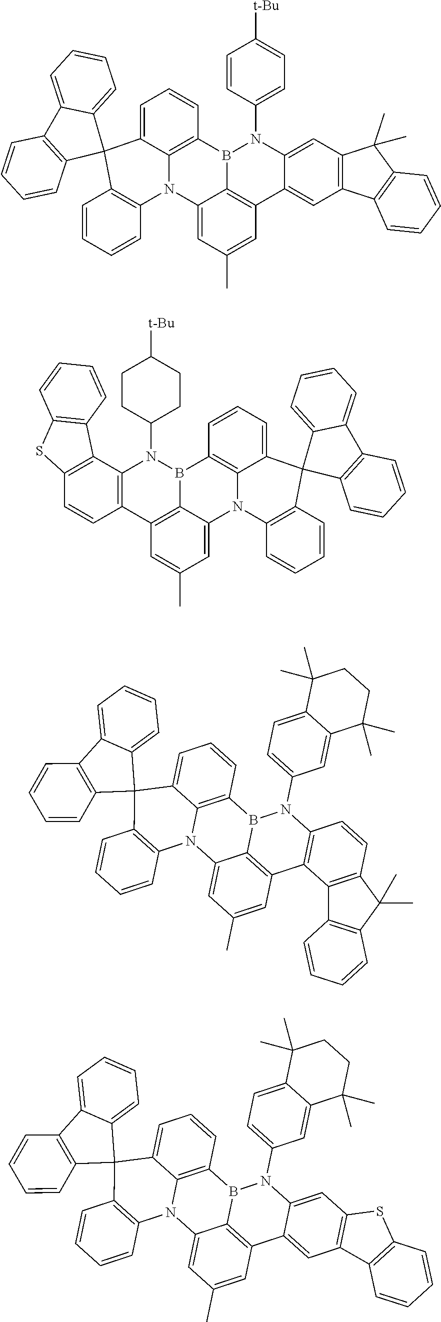 [SMILES: Cc1cc2c3c(c1)N1c4ccccc4C4(c5ccccc5-c5ccccc54)c4cccc(c41)B3N(c1ccc(C(C)(C)C)cc1)c1cc3c(cc1-2)-c1ccccc1C3(C)C ; Cc1cc2c3c(c1)N1c4ccccc4C4(c5ccccc5-c5ccccc54)c4cccc(c41)B3N(C1CCC(C(C)(C)C)CC1)c1c-2ccc2sc3ccccc3c12 ; Cc1cc2c3c(c1)N1c4ccccc4C4(c5ccccc5-c5ccccc54)c4cccc(c41)B3N(c1ccc3c(c1)C(C)(C)CCC3(C)C)c1ccc3c(c1-2)-c1ccccc1C3(C)C ; Cc1cc2c3c(c1)N1c4ccccc4C4(c5ccccc5-c5ccccc54)c4cccc(c41)B3N(c1ccc3c(c1)C(C)(C)CCC3(C)C)c1cc3sc4ccccc4c3cc1-2] 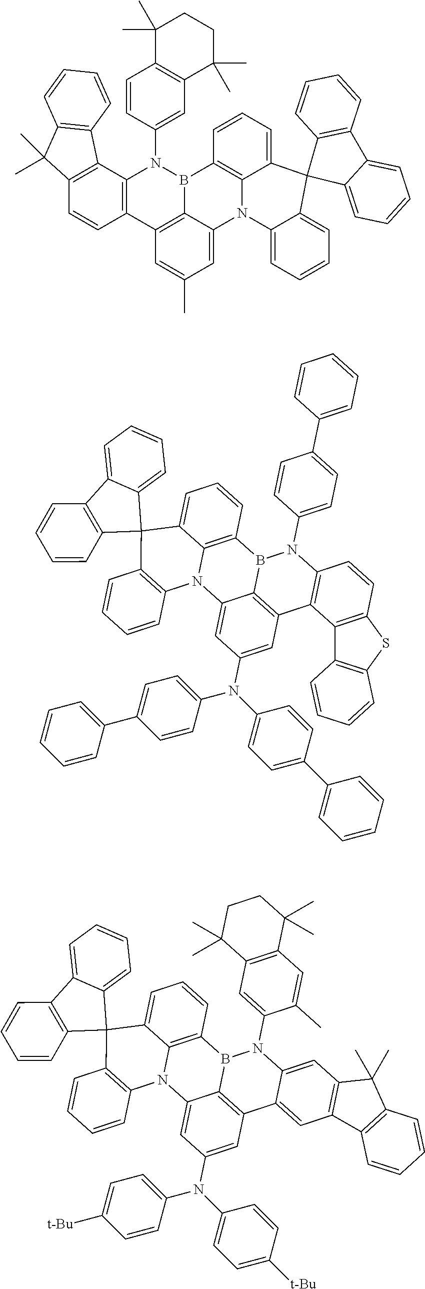 [SMILES: Cc1cc2c3c(c1)N1c4ccccc4C4(c5ccccc5-c5ccccc54)c4cccc(c41)B3N(c1ccc3c(c1)C(C)(C)CCC3(C)C)c1c-2ccc2c1-c1ccccc1C2(C)C ; c1ccc(-c2ccc(N3B4c5cccc6c5N(c5ccccc5C65c6ccccc6-c6ccccc65)c5cc(N(c6ccc(-c7ccccc7)cc6)c6ccc(-c7ccccc7)cc6)cc(c54)-c4c3ccc3sc5ccccc5c43)cc2)cc1 ; Cc1cc2c(cc1N1B3c4cccc5c4N(c4ccccc4C54c5ccccc5-c5ccccc54)c4cc(N(c5ccc(C(C)(C)C)cc5)c5ccc(C(C)(C)C)cc5)cc(c43)-c3cc4c(cc31)C(C)(C)c1ccccc1-4)C(C)(C)CCC2(C)C] 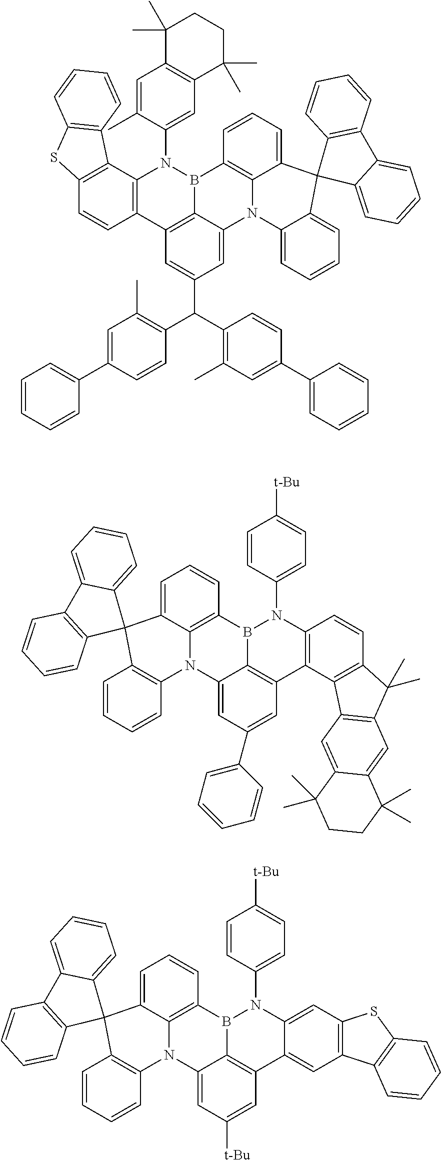 [SMILES: Cc1cc(-c2ccccc2)ccc1C(c1cc2c3c(c1)N1c4ccccc4C4(c5ccccc5-c5ccccc54)c4cccc(c41)B3N(c1cc3c(cc1C)C(C)(C)CCC3(C)C)c1c-2ccc2sc3ccccc3c12)c1ccc(-c2ccccc2)cc1C ; CC(C)(C)c1ccc(N2B3c4cccc5c4N(c4ccccc4C54c5ccccc5-c5ccccc54)c4cc(-c5ccccc5)cc(c43)-c3c2ccc2c3-c3cc4c(cc3C2(C)C)C(C)(C)CCC4(C)C)cc1 ; CC(C)(C)c1ccc(N2B3c4cccc5c4N(c4ccccc4C54c5ccccc5-c5ccccc54)c4cc(C(C)(C)C)cc(c43)-c3cc4c(cc32)sc2ccccc24)cc1] 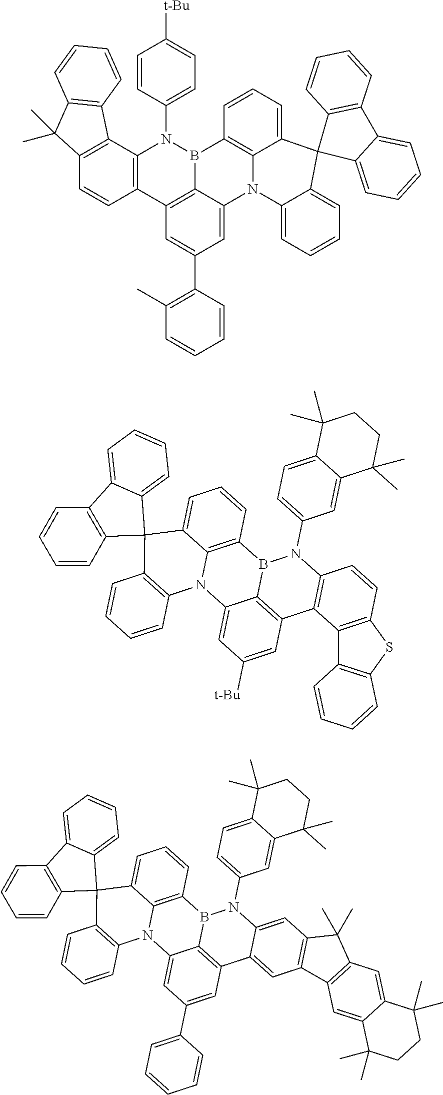 [SMILES: Cc1ccccc1-c1cc2c3c(c1)N1c4ccccc4C4(c5ccccc5-c5ccccc54)c4cccc(c41)B3N(c1ccc(C(C)(C)C)cc1)c1c-2ccc2c1-c1ccccc1C2(C)C ; CC(C)(C)c1cc2c3c(c1)N1c4ccccc4C4(c5ccccc5-c5ccccc54)c4cccc(c41)B3N(c1ccc3c(c1)C(C)(C)CCC3(C)C)c1ccc3sc4ccccc4c3c1-2 ; CC1(C)CCC(C)(C)c2cc(N3B4c5cccc6c5N(c5ccccc5C65c6ccccc6-c6ccccc65)c5cc(-c6ccccc6)cc(c54)-c4cc5c(cc43)C(C)(C)c3cc4c(cc3-5)C(C)(C)CCC4(C)C)ccc21] 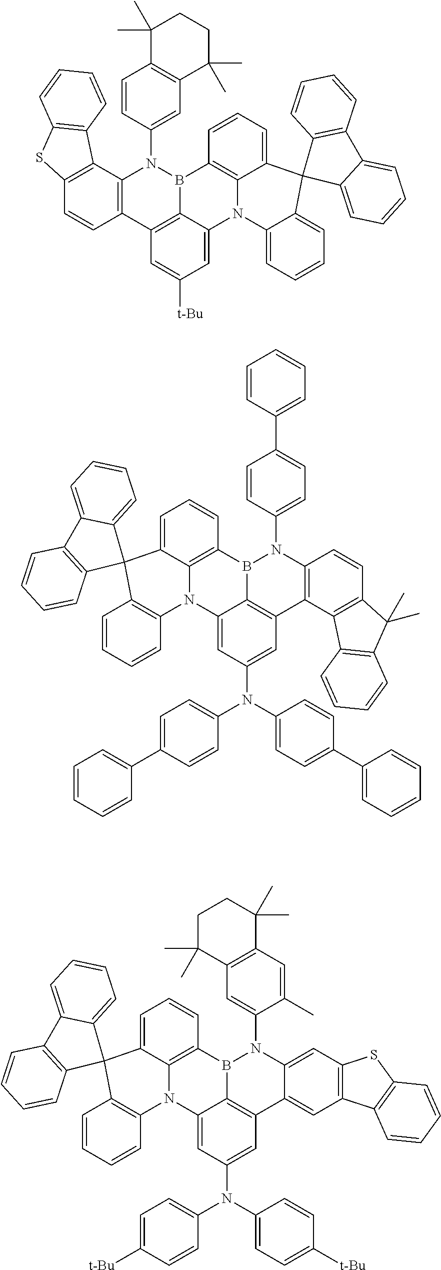 [SMILES: CC(C)(C)c1cc2c3c(c1)N1c4ccccc4C4(c5ccccc5-c5ccccc54)c4cccc(c41)B3N(c1ccc3c(c1)C(C)(C)CCC3(C)C)c1c-2ccc2sc3ccccc3c12 ; CC1(C)c2ccccc2-c2c1ccc1c2-c2cc(N(c3ccc(-c4ccccc4)cc3)c3ccc(-c4ccccc4)cc3)cc3c2B(c2cccc4c2N3c2ccccc2C42c3ccccc3-c3ccccc32)N1c1ccc(-c2ccccc2)cc1 ; Cc1cc2c(cc1N1B3c4cccc5c4N(c4ccccc4C54c5ccccc5-c5ccccc54)c4cc(N(c5ccc(C(C)(C)C)cc5)c5ccc(C(C)(C)C)cc5)cc(c43)-c3cc4c(cc31)sc1ccccc14)C(C)(C)CCC2(C)C] 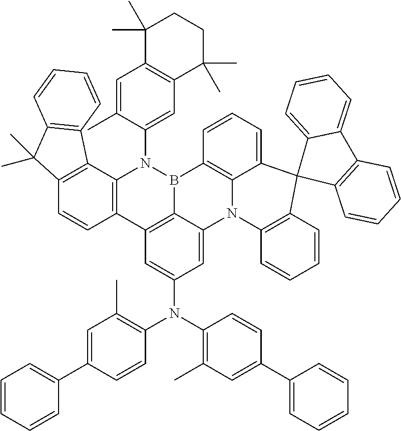 [SMILES: Cc1cc2c(cc1N1B3c4cccc5c4N(c4ccccc4C54c5ccccc5-c5ccccc54)c4cc(N(c5ccc(-c6ccccc6)cc5C)c5ccc(-c6ccccc6)cc5C)cc(c43)-c3ccc4c(c31)-c1ccccc1C4(C)C)C(C)(C)CCC2(C)C] 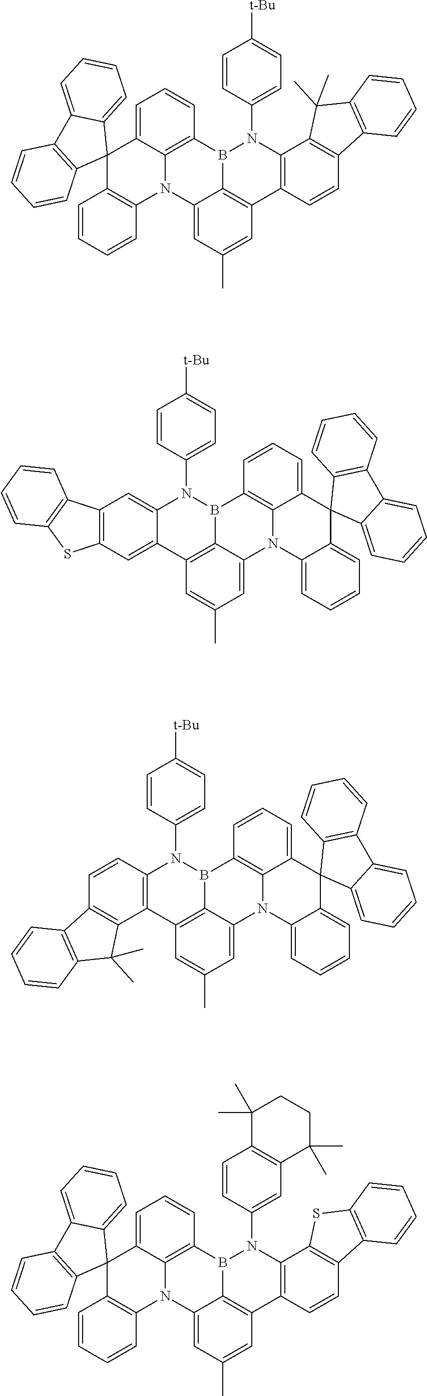 [SMILES: Cc1cc2c3c(c1)N1c4ccccc4C4(c5ccccc5-c5ccccc54)c4cccc(c41)B3N(c1ccc(C(C)(C)C)cc1)c1c-2ccc2c1C(C)(C)c1ccccc1-2 ; Cc1cc2c3c(c1)N1c4ccccc4C4(c5ccccc5-c5ccccc54)c4cccc(c41)B3N(c1ccc(C(C)(C)C)cc1)c1cc3c(cc1-2)sc1ccccc13 ; Cc1cc2c3c(c1)N1c4ccccc4C4(c5ccccc5-c5ccccc54)c4cccc(c41)B3N(c1ccc(C(C)(C)C)cc1)c1ccc3c(c1-2)C(C)(C)c1ccccc1-3 ; Cc1cc2c3c(c1)N1c4ccccc4C4(c5ccccc5-c5ccccc54)c4cccc(c41)B3N(c1ccc3c(c1)C(C)(C)CCC3(C)C)c1c-2ccc2c1sc1ccccc12] 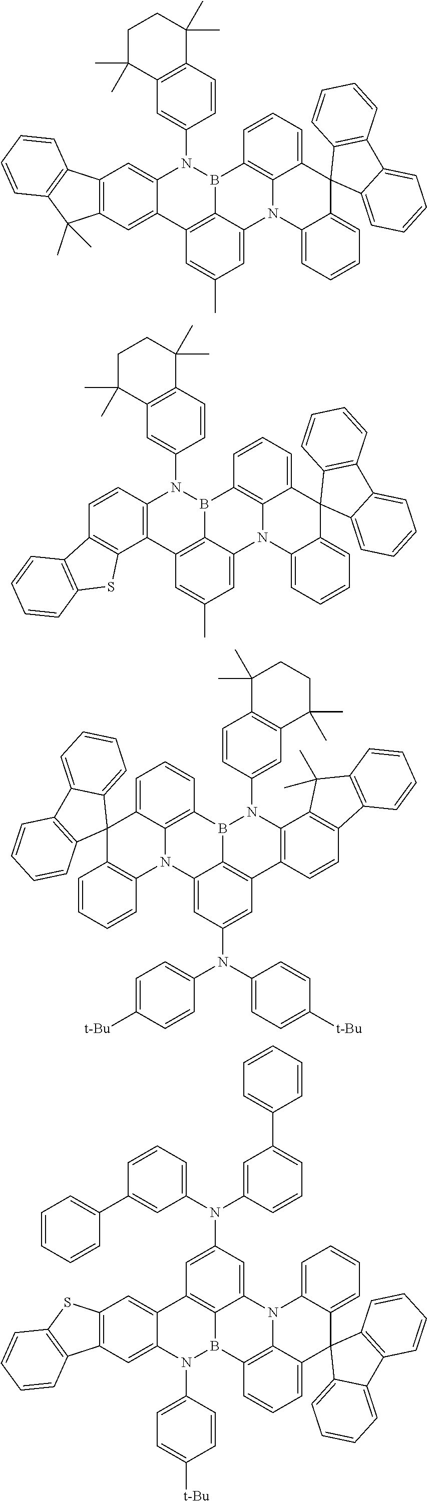 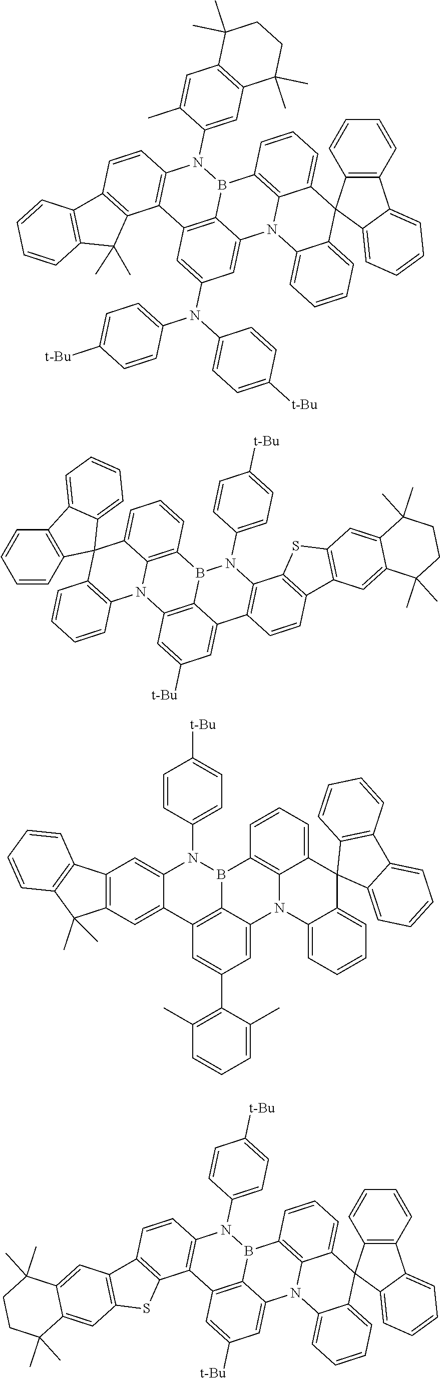 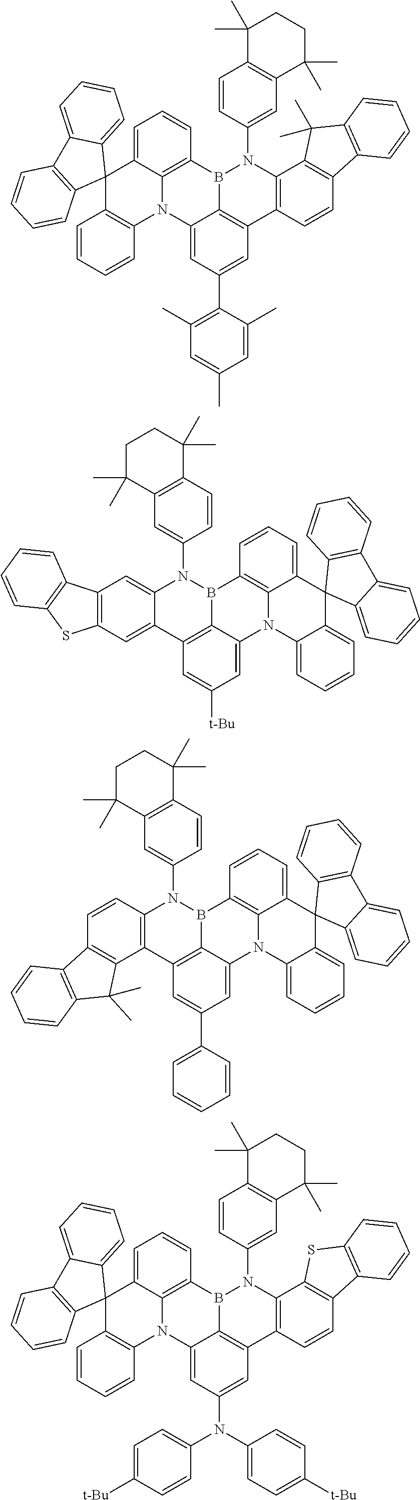 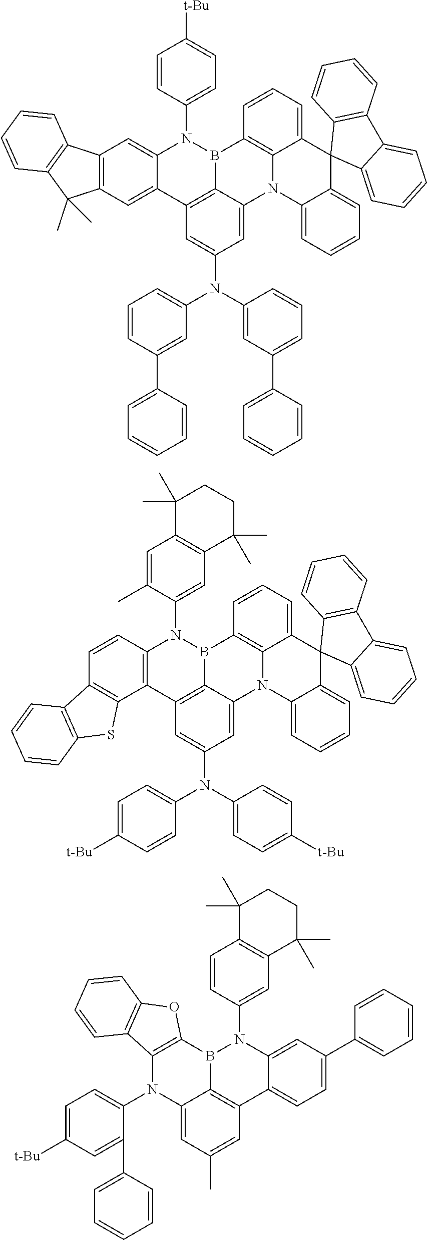 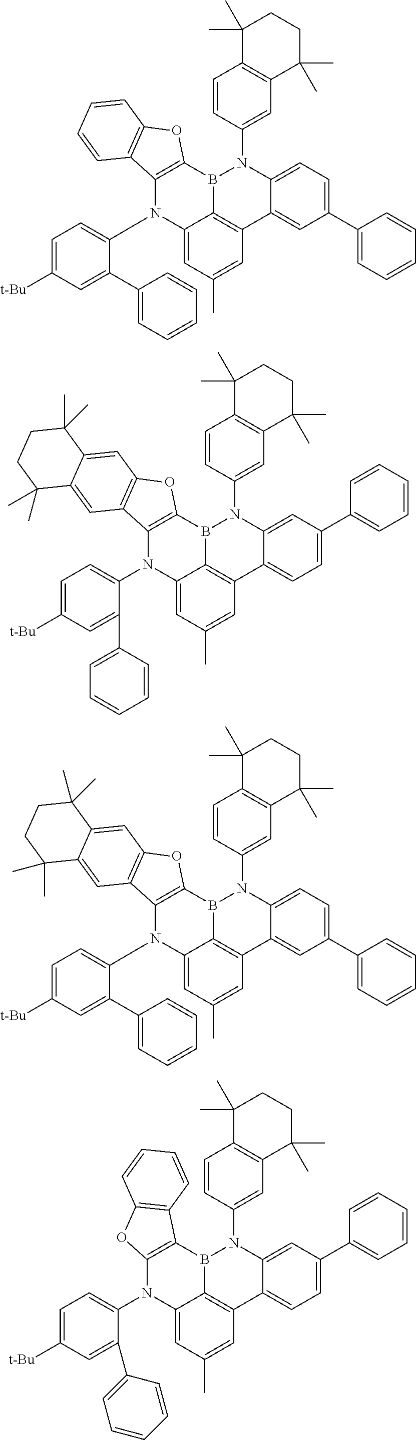 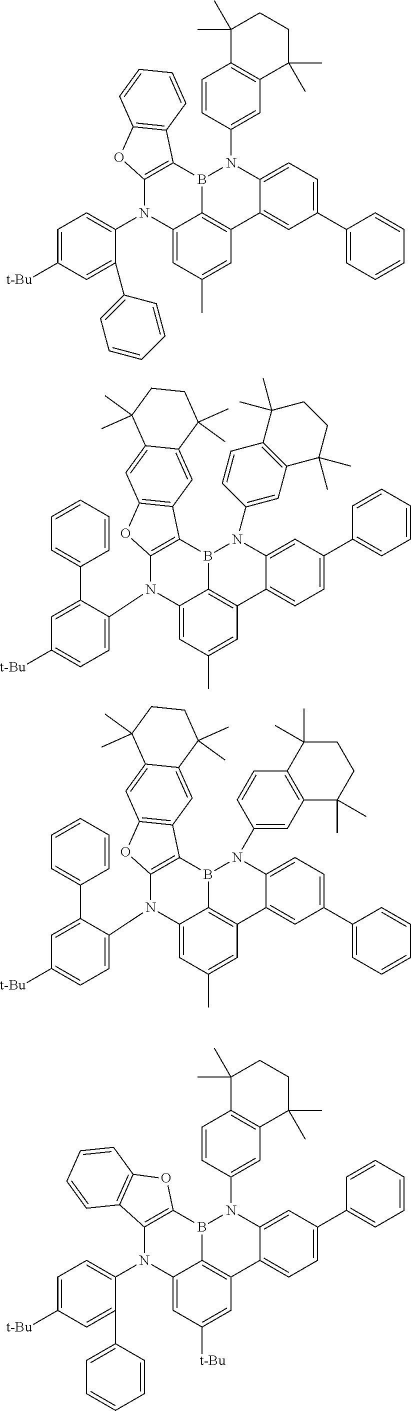 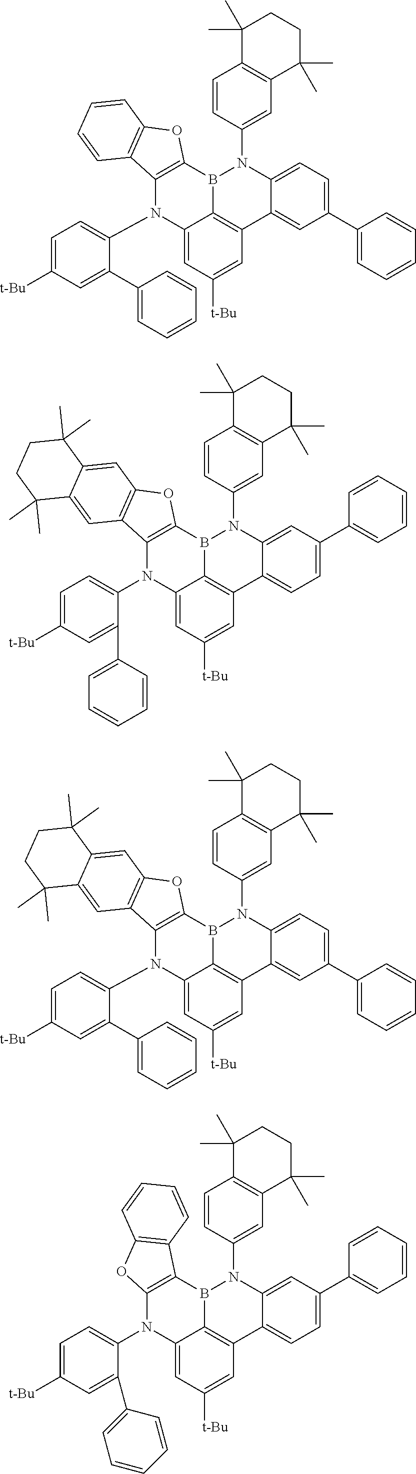 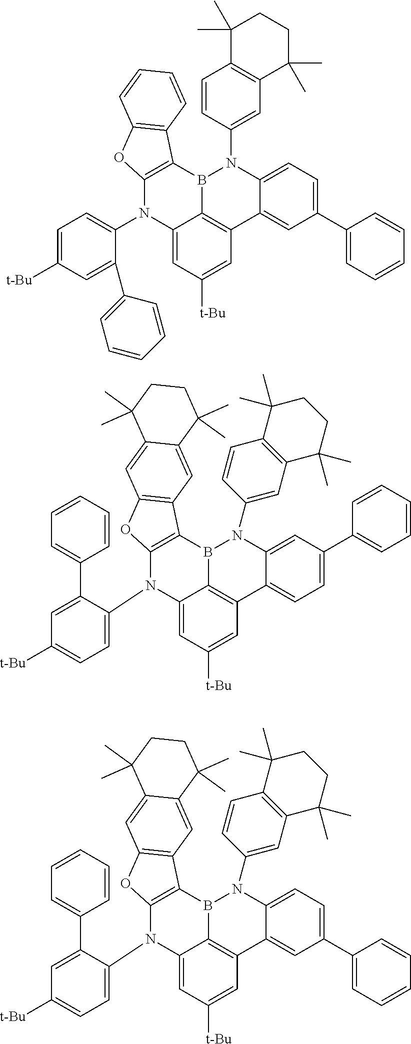 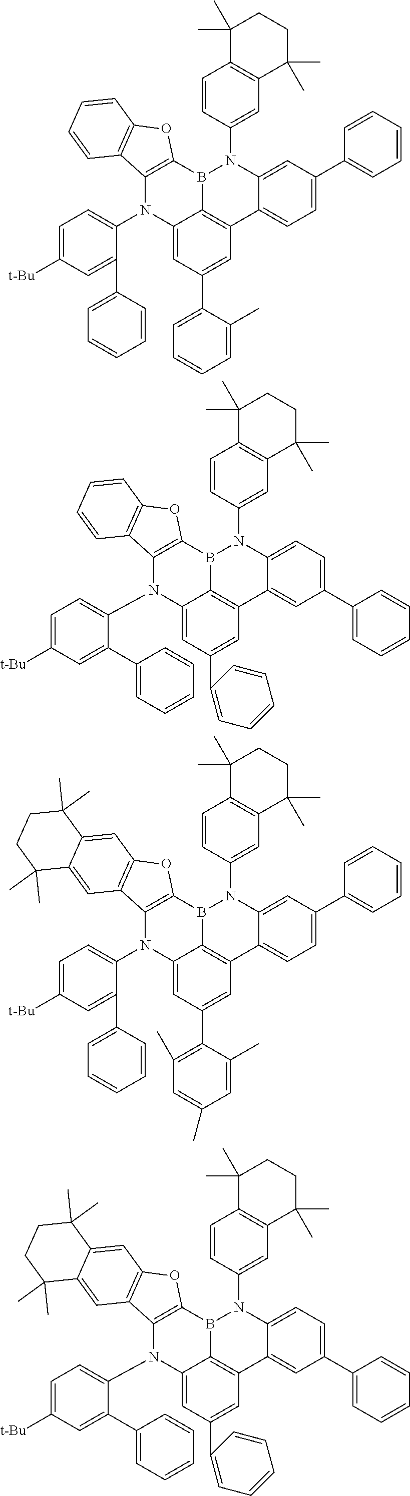 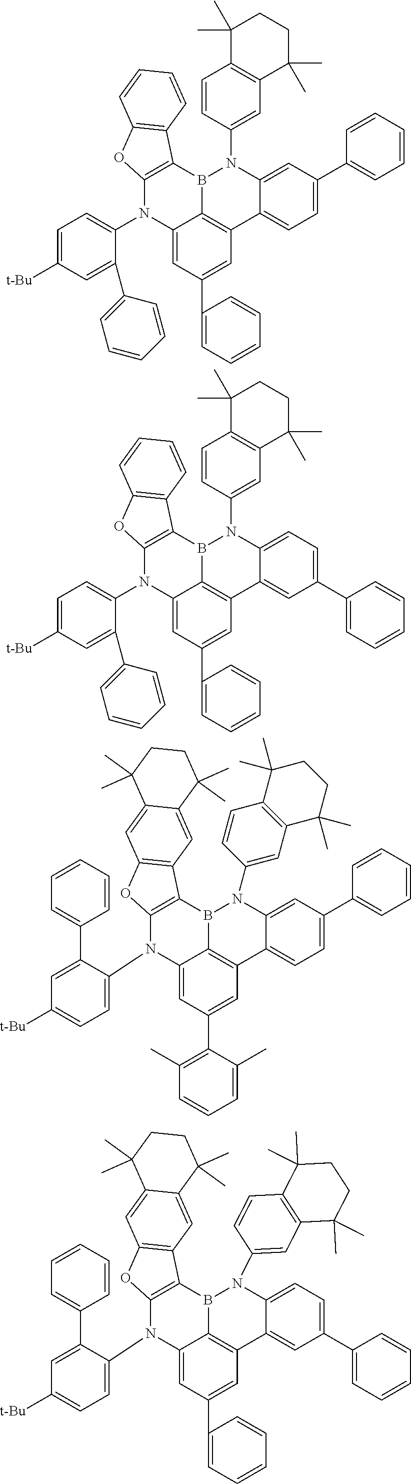 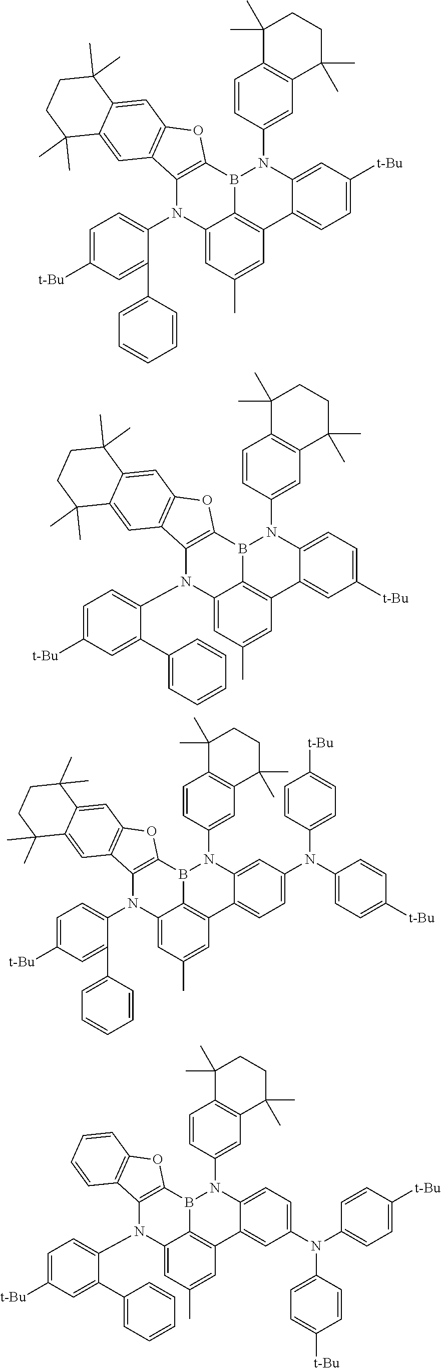 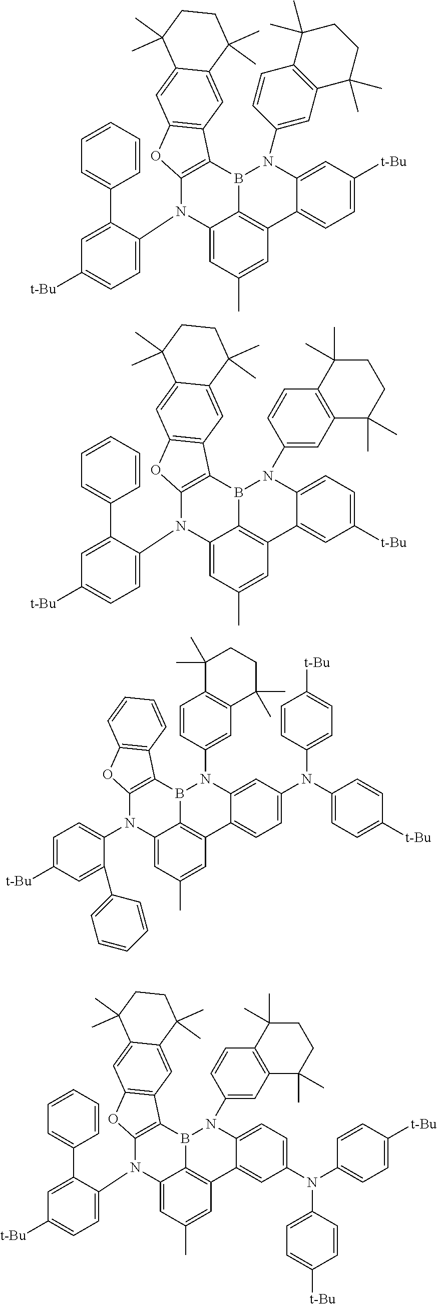 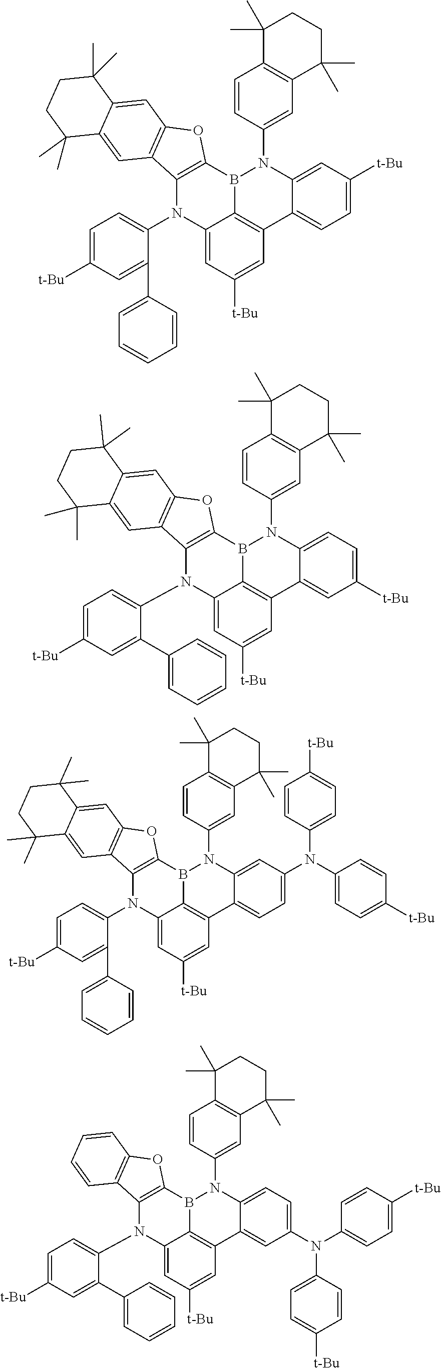 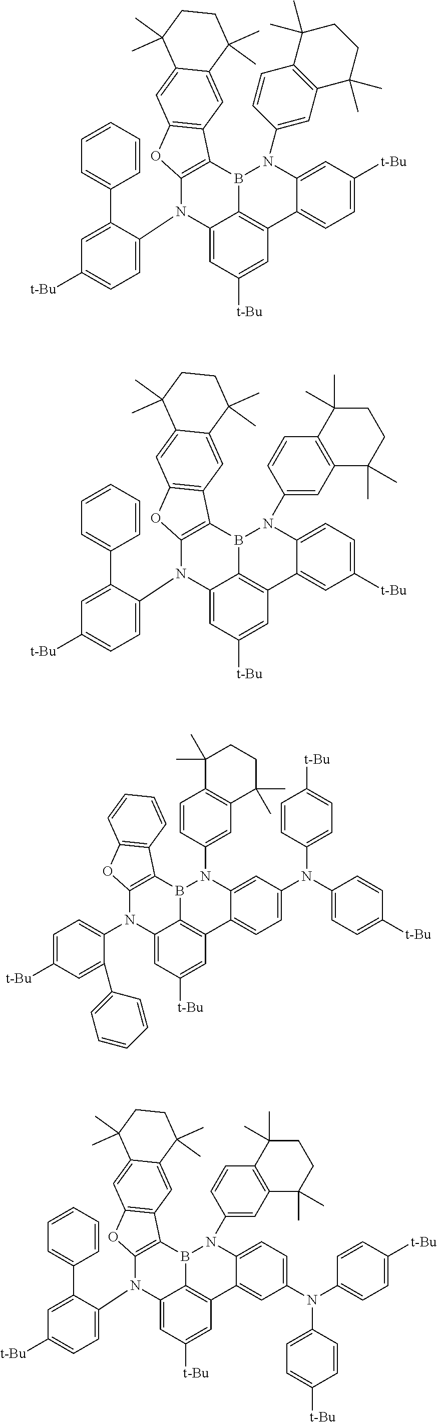 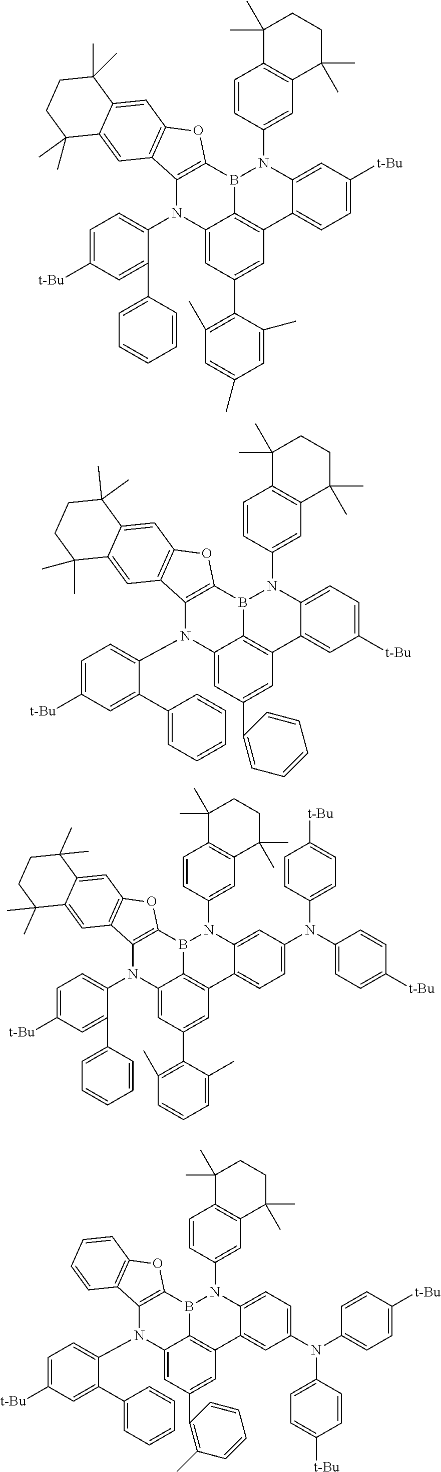 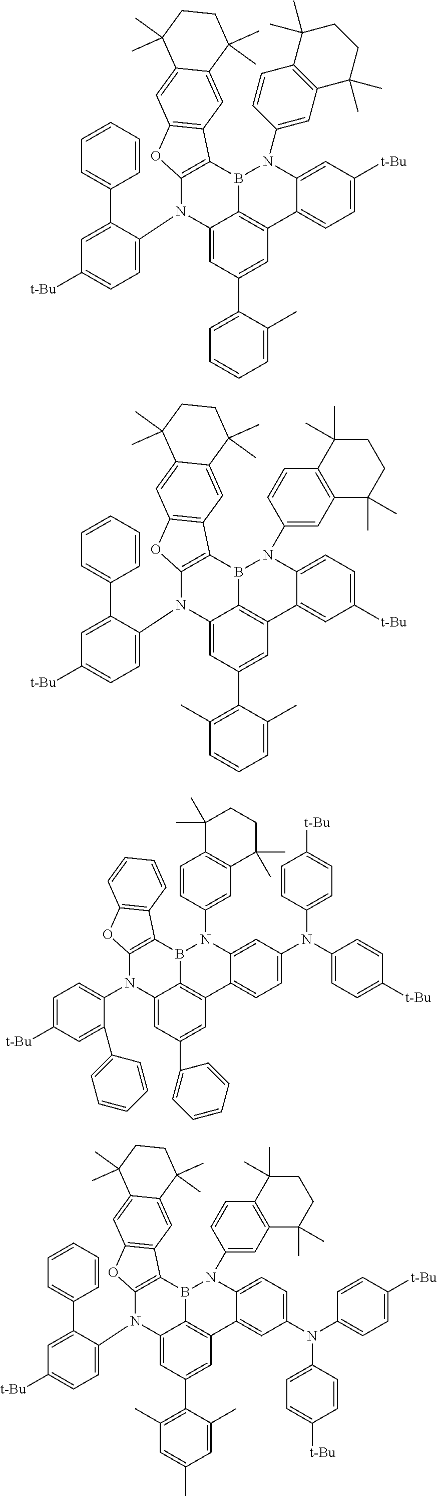 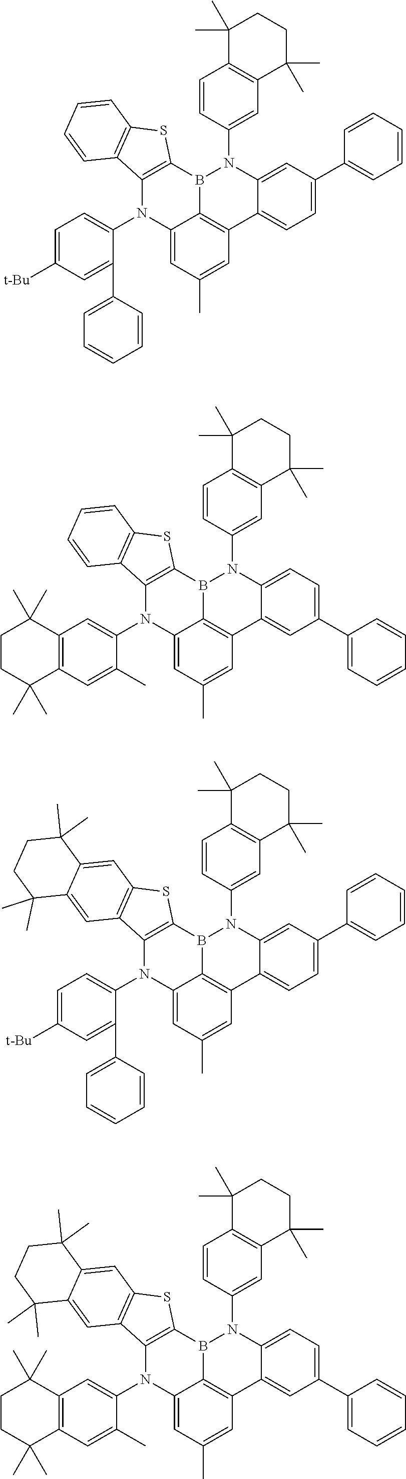 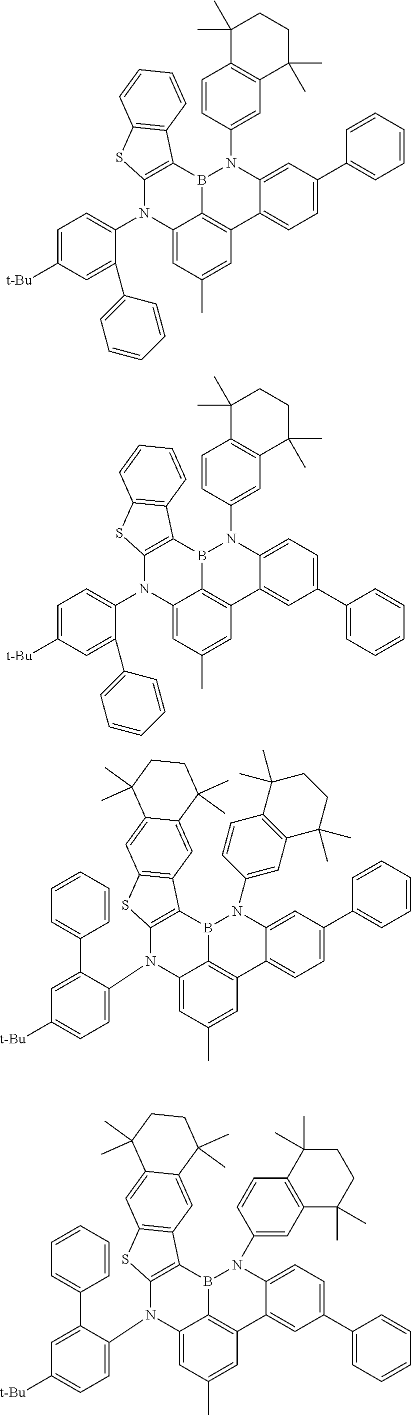 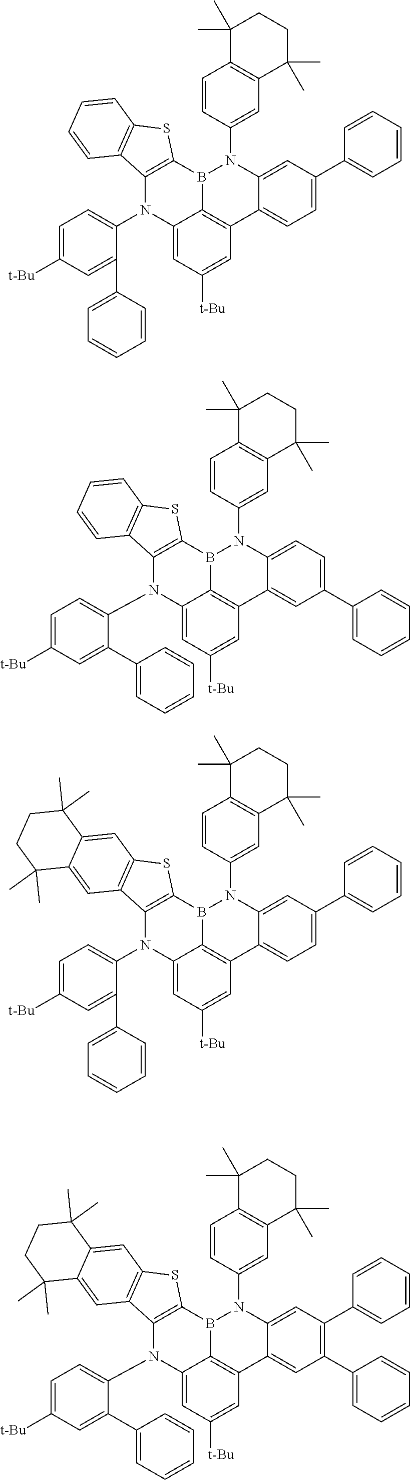 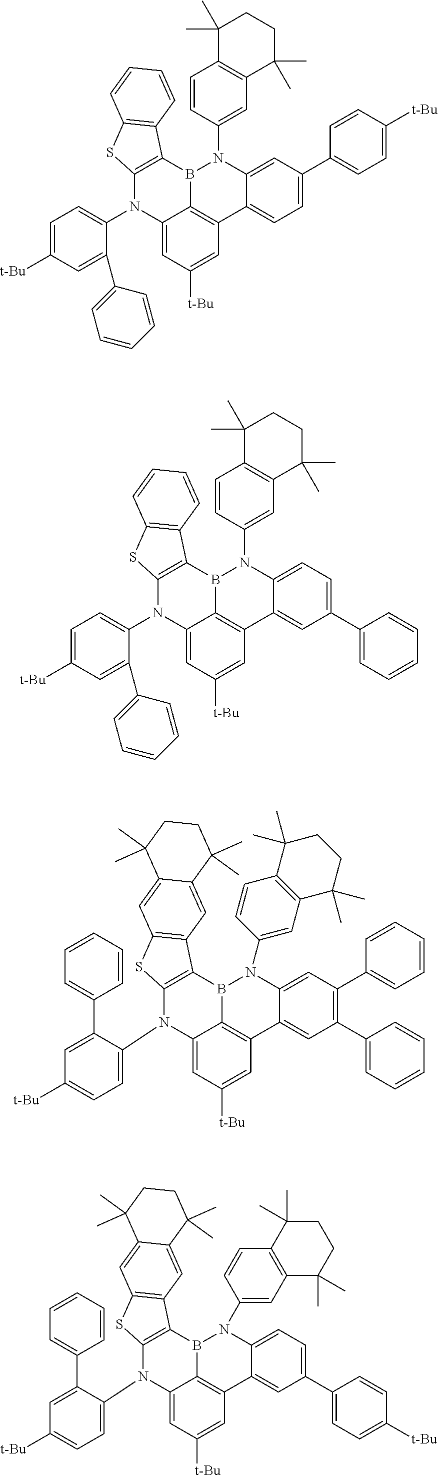 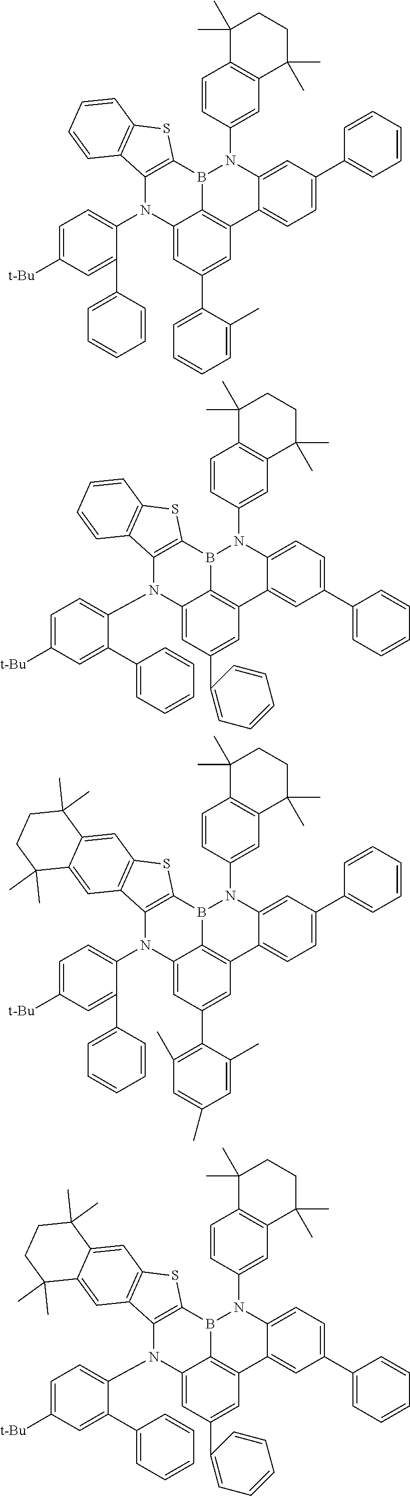 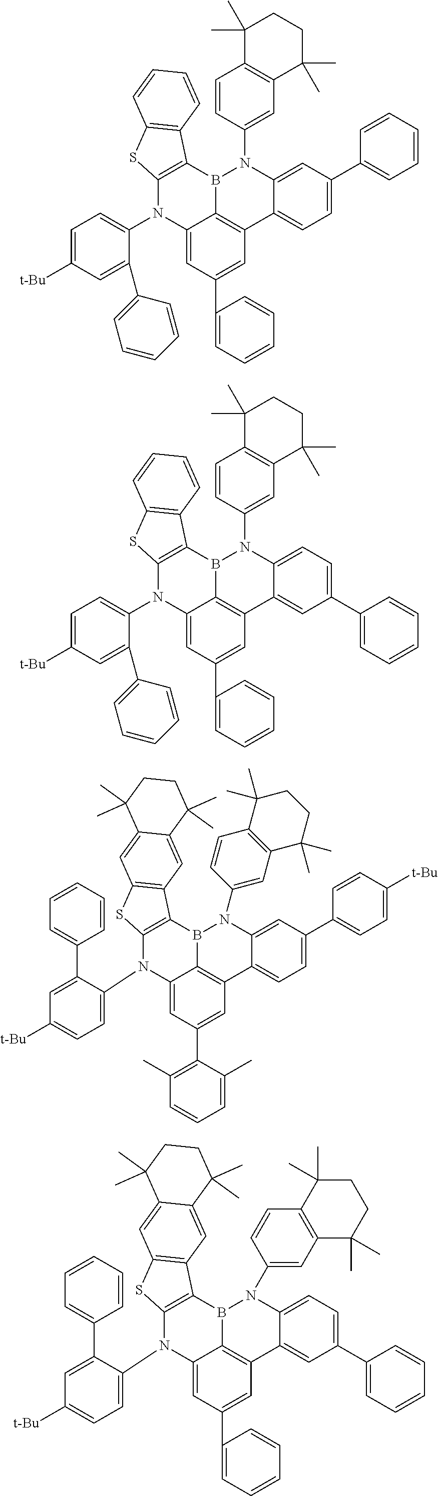 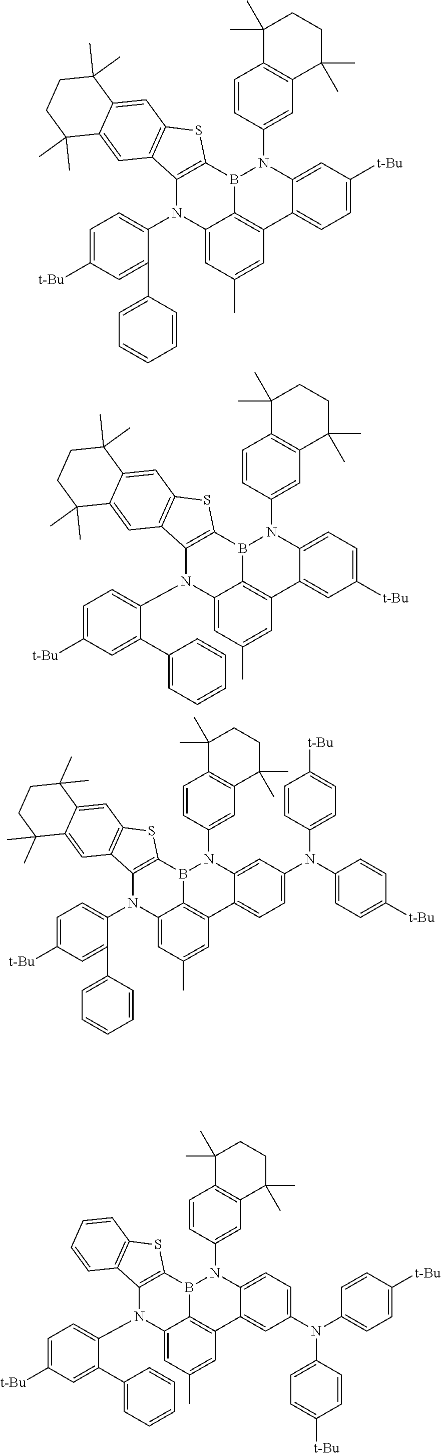 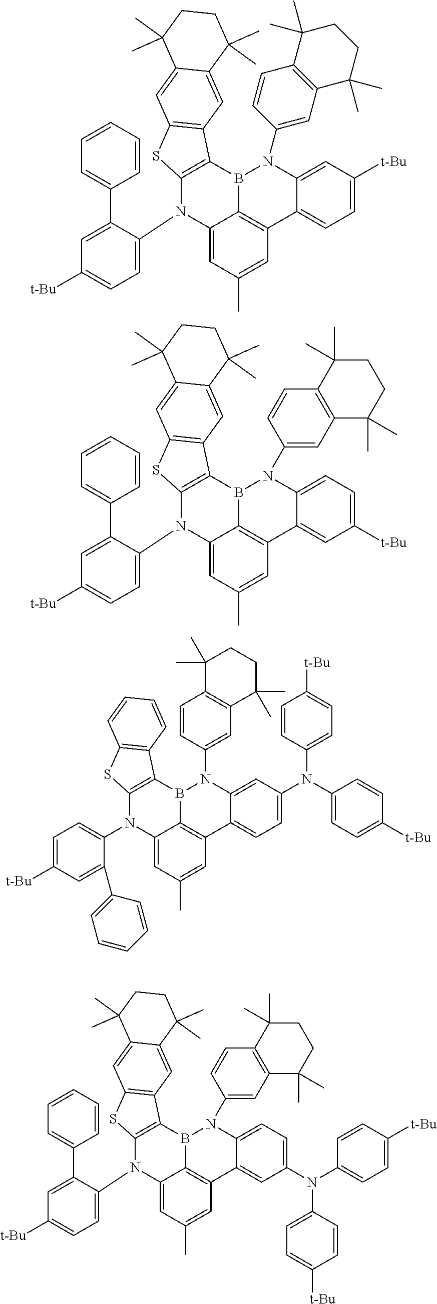 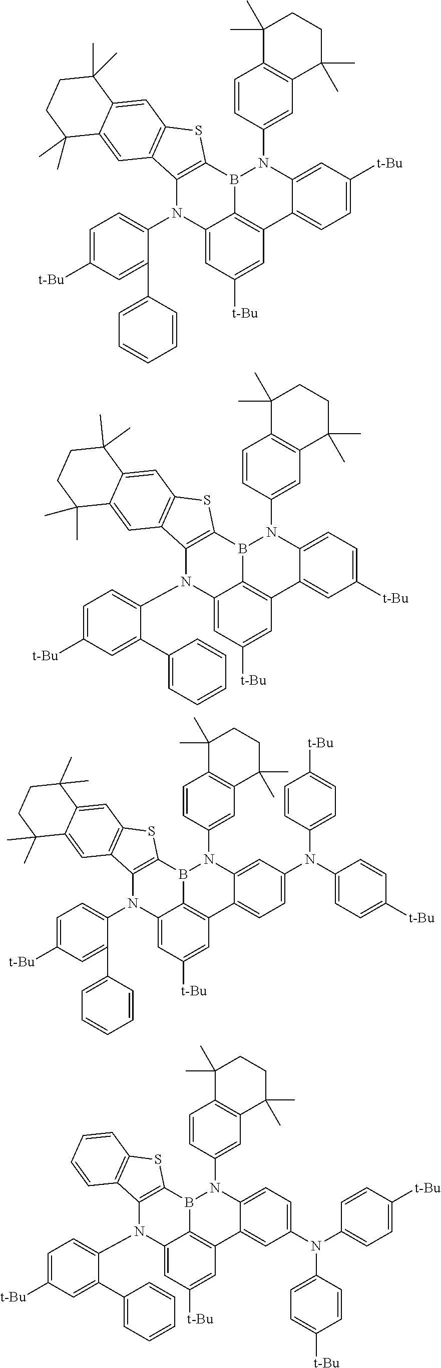 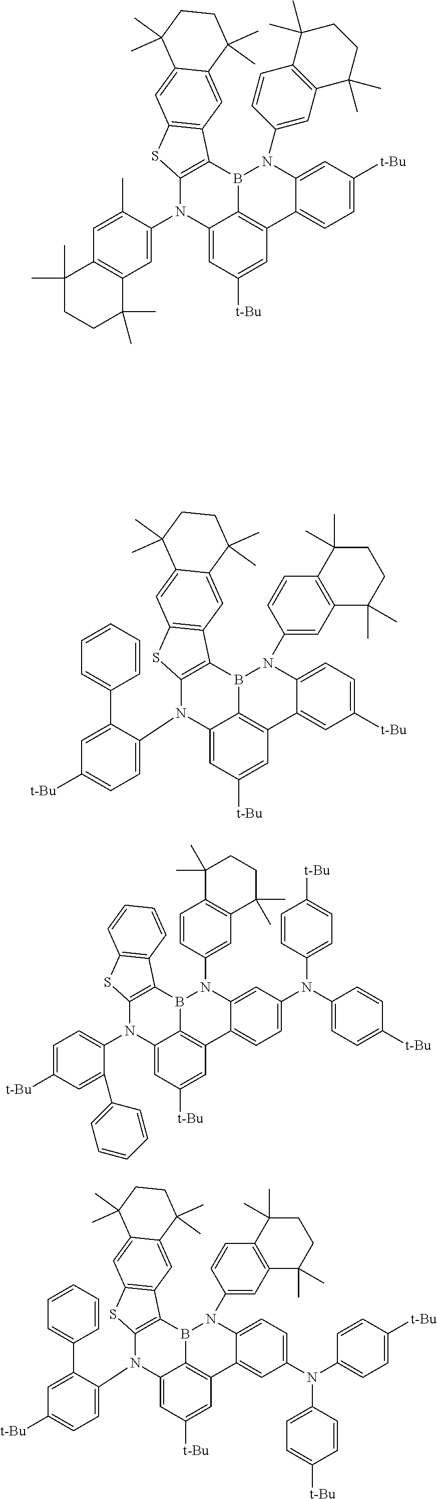 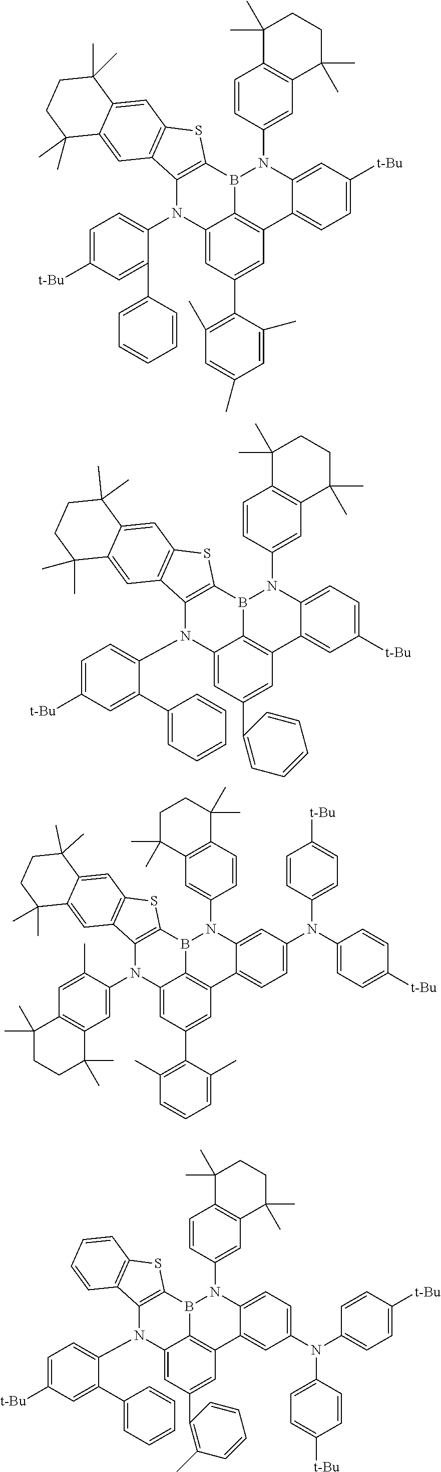 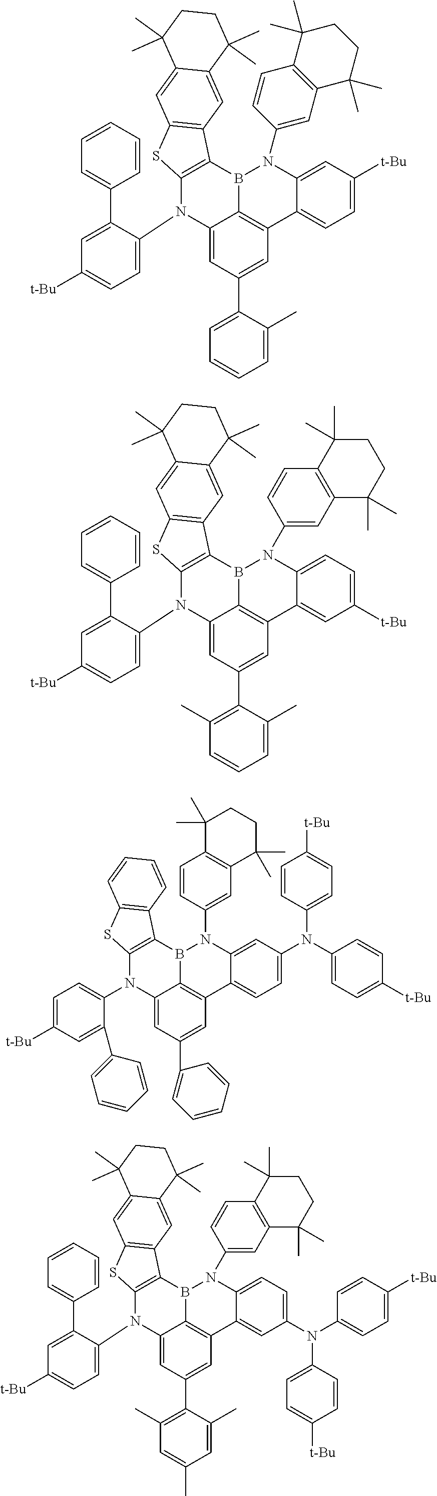 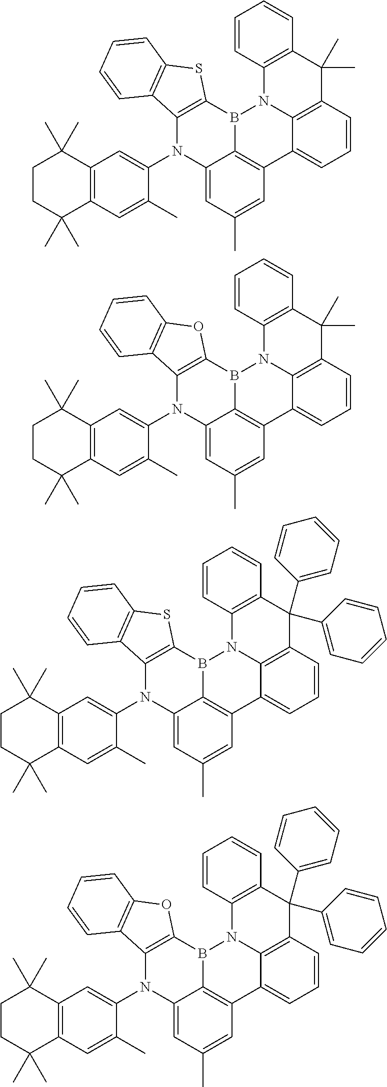 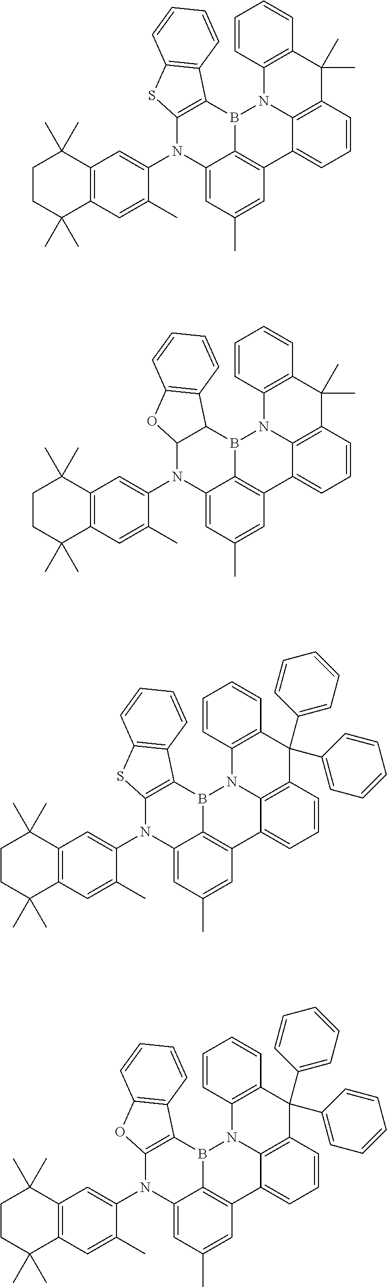 [SMILES: Cc1cc2c3c(c1)N(c1cc4c(cc1C)C(C)(C)CCC4(C)C)c1sc4ccccc4c1B3N1c3ccccc3C(C)(C)c3cccc-2c31 ; Cc1cc2c3c(c1)N(c1cc4c(cc1C)C(C)(C)CCC4(C)C)C1Oc4ccccc4C1B3N1c3ccccc3C(C)(C)c3cccc-2c31 ; Cc1cc2c3c(c1)N(c1cc4c(cc1C)C(C)(C)CCC4(C)C)c1sc4ccccc4c1B3N1c3ccccc3C(c3ccccc3)(c3ccccc3)c3cccc-2c31 ; Cc1cc2c3c(c1)N(c1cc4c(cc1C)C(C)(C)CCC4(C)C)c1oc4ccccc4c1B3N1c3ccccc3C(c3ccccc3)(c3ccccc3)c3cccc-2c31] 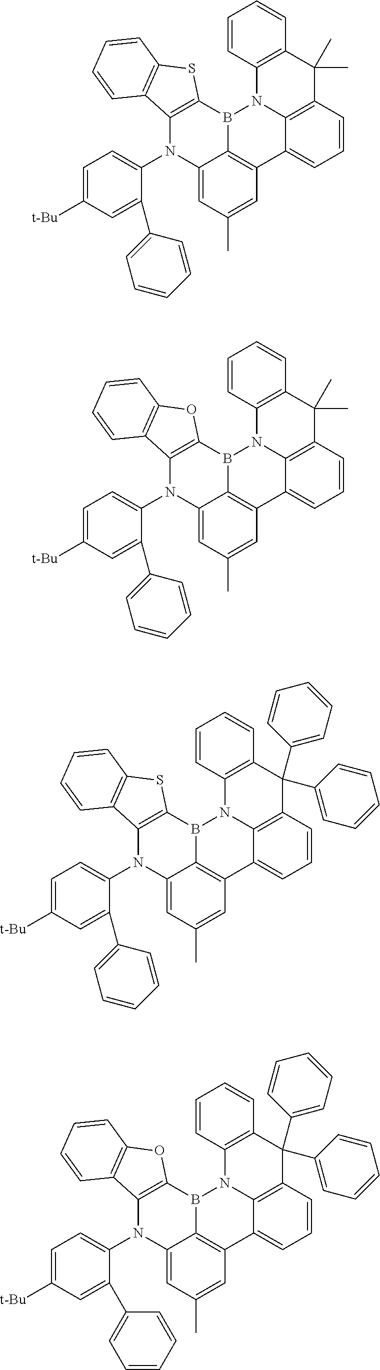 [SMILES: Cc1cc2c3c(c1)N(c1ccc(C(C)(C)C)cc1-c1ccccc1)c1c(sc4ccccc14)B3N1c3ccccc3C(C)(C)c3cccc-2c31 ; Cc1cc2c3c(c1)N(c1ccc(C(C)(C)C)cc1-c1ccccc1)c1c(oc4ccccc14)B3N1c3ccccc3C(C)(C)c3cccc-2c31 ; Cc1cc2c3c(c1)N(c1ccc(C(C)(C)C)cc1-c1ccccc1)c1c(sc4ccccc14)B3N1c3ccccc3C(c3ccccc3)(c3ccccc3)c3cccc-2c31 ; Cc1cc2c3c(c1)N(c1ccc(C(C)(C)C)cc1-c1ccccc1)c1c(oc4ccccc14)B3N1c3ccccc3C(c3ccccc3)(c3ccccc3)c3cccc-2c31] 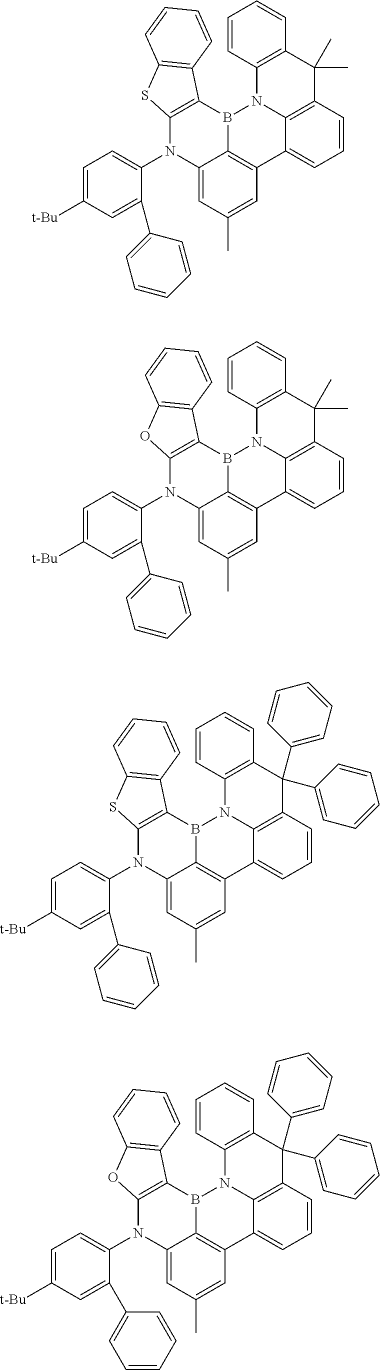 [SMILES: Cc1cc2c3c(c1)N(c1ccc(C(C)(C)C)cc1-c1ccccc1)c1sc4ccccc4c1B3N1c3ccccc3C(C)(C)c3cccc-2c31 ; Cc1cc2c3c(c1)N(c1ccc(C(C)(C)C)cc1-c1ccccc1)c1oc4ccccc4c1B3N1c3ccccc3C(C)(C)c3cccc-2c31 ; Cc1cc2c3c(c1)N(c1ccc(C(C)(C)C)cc1-c1ccccc1)c1sc4ccccc4c1B3N1c3ccccc3C(c3ccccc3)(c3ccccc3)c3cccc-2c31 ; Cc1cc2c3c(c1)N(c1ccc(C(C)(C)C)cc1-c1ccccc1)c1oc4ccccc4c1B3N1c3ccccc3C(c3ccccc3)(c3ccccc3)c3cccc-2c31] 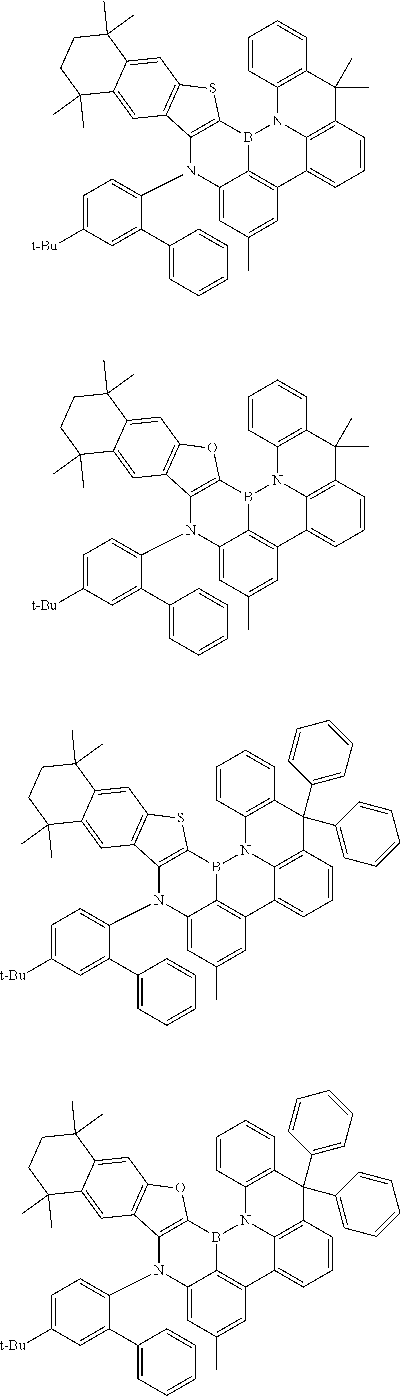 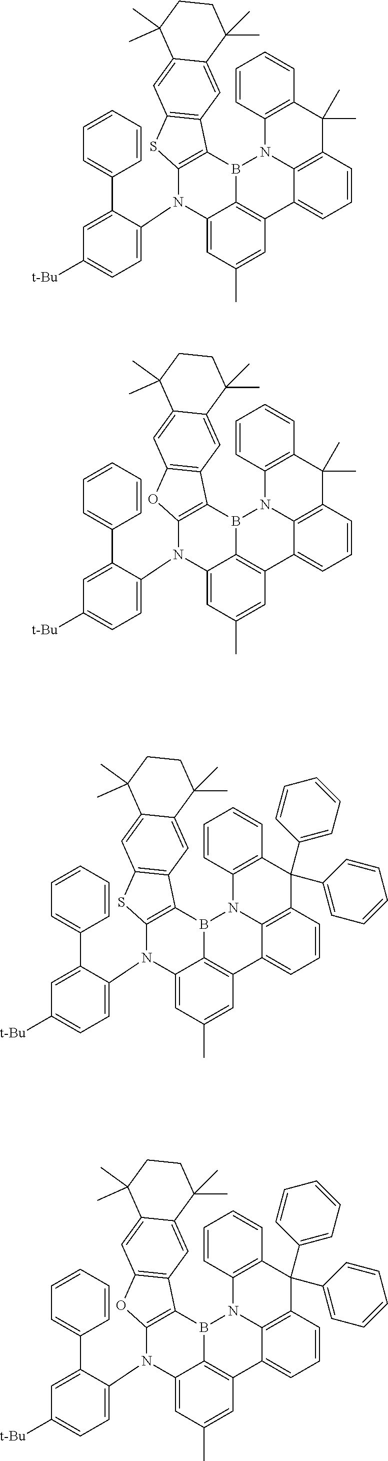 [SMILES: Cc1cc2c3c(c1)N(c1ccc(C(C)(C)C)cc1-c1ccccc1)c1sc4cc5c(cc4c1B3N1c3ccccc3C(C)(C)c3cccc-2c31)C(C)(C)CCC5(C)C ; Cc1cc2c3c(c1)N(c1ccc(C(C)(C)C)cc1-c1ccccc1)c1oc4cc5c(cc4c1B3N1c3ccccc3C(C)(C)c3cccc-2c31)C(C)(C)CCC5(C)C ; Cc1cc2c3c(c1)N(c1ccc(C(C)(C)C)cc1-c1ccccc1)c1sc4cc5c(cc4c1B3N1c3ccccc3C(c3ccccc3)(c3ccccc3)c3cccc-2c31)C(C)(C)CCC5(C)C ; Cc1cc2c3c(c1)N(c1ccc(C(C)(C)C)cc1-c1ccccc1)c1oc4cc5c(cc4c1B3N1c3ccccc3C(c3ccccc3)(c3ccccc3)c3cccc-2c31)C(C)(C)CCC5(C)C] 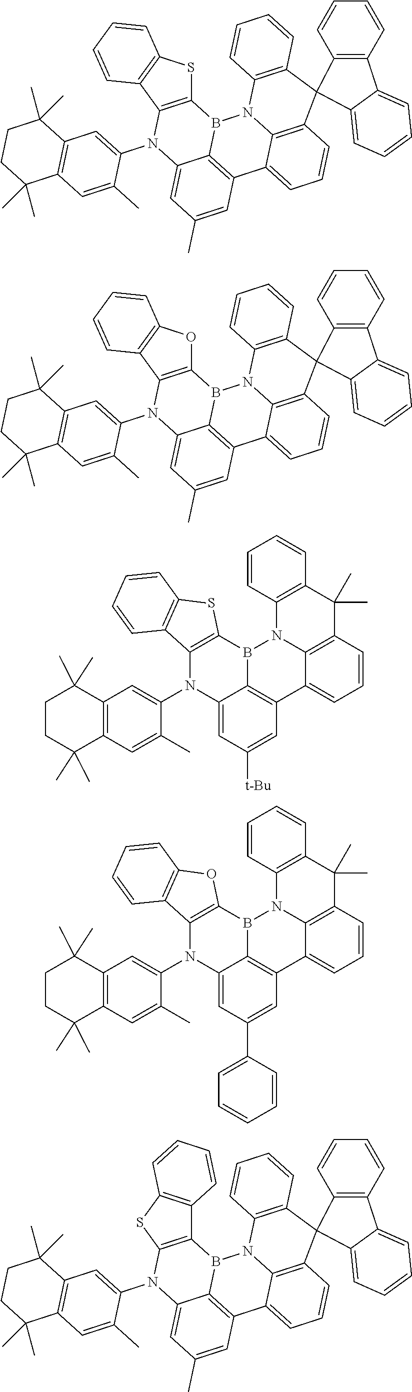 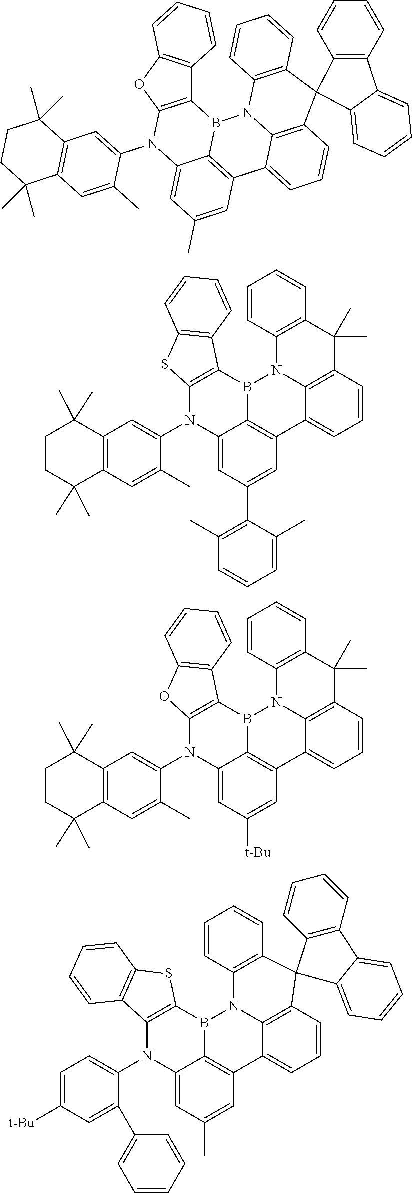 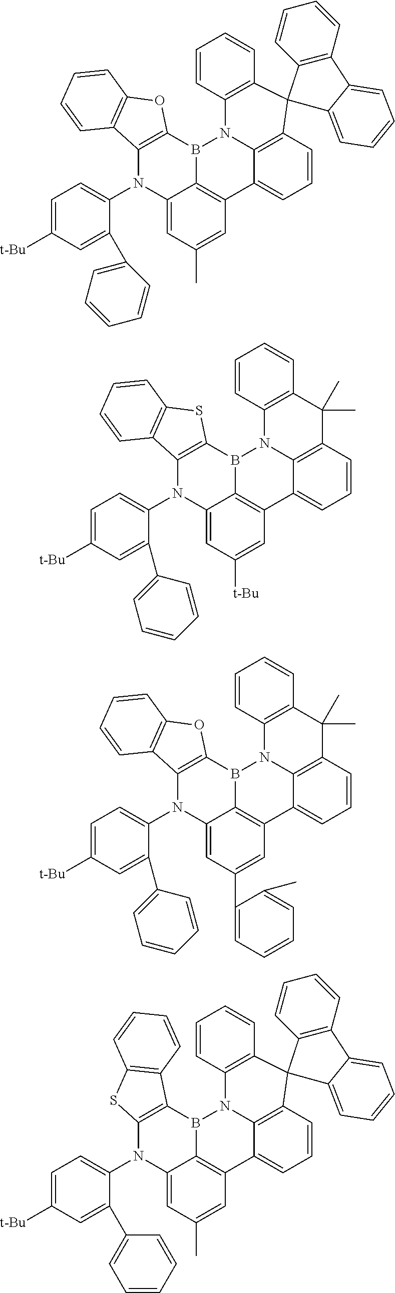 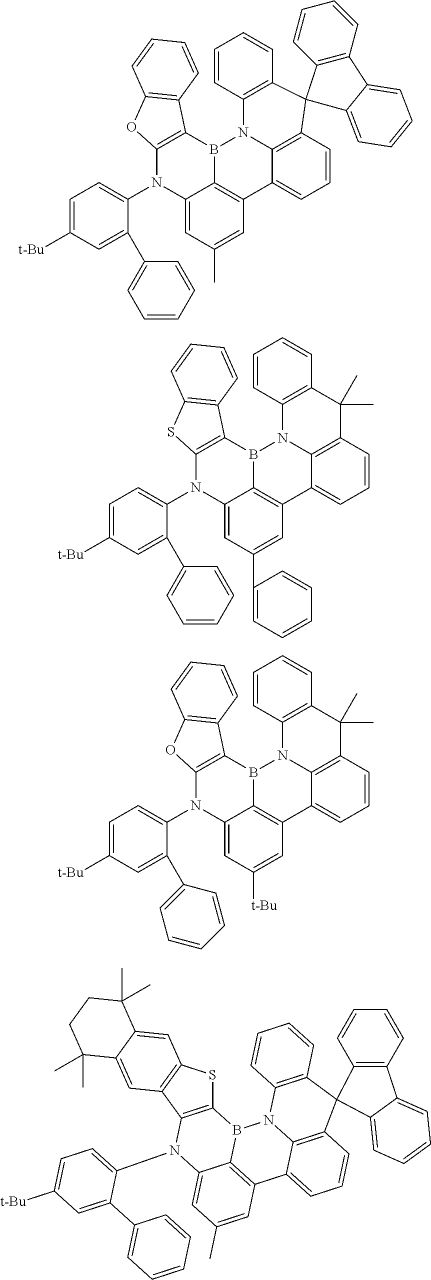 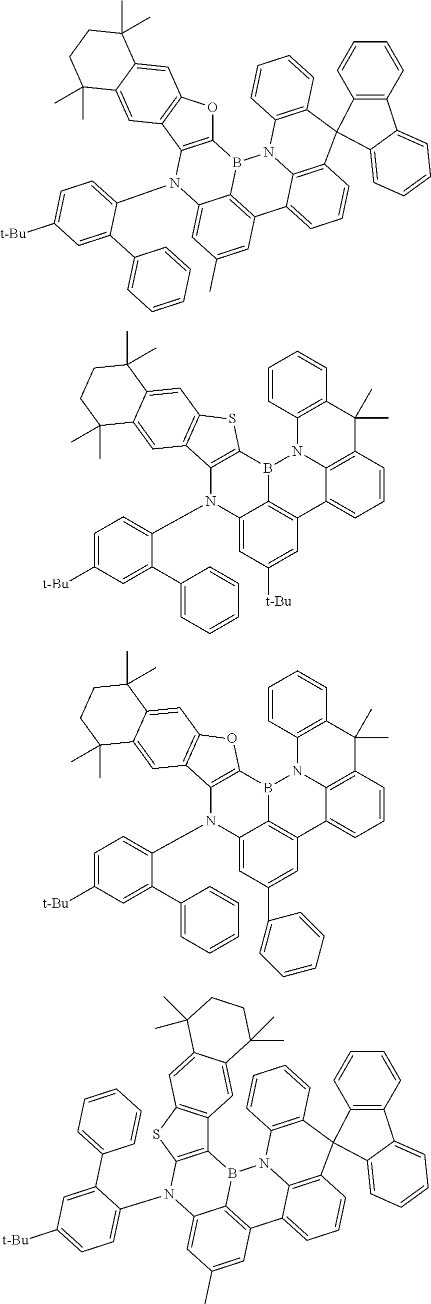 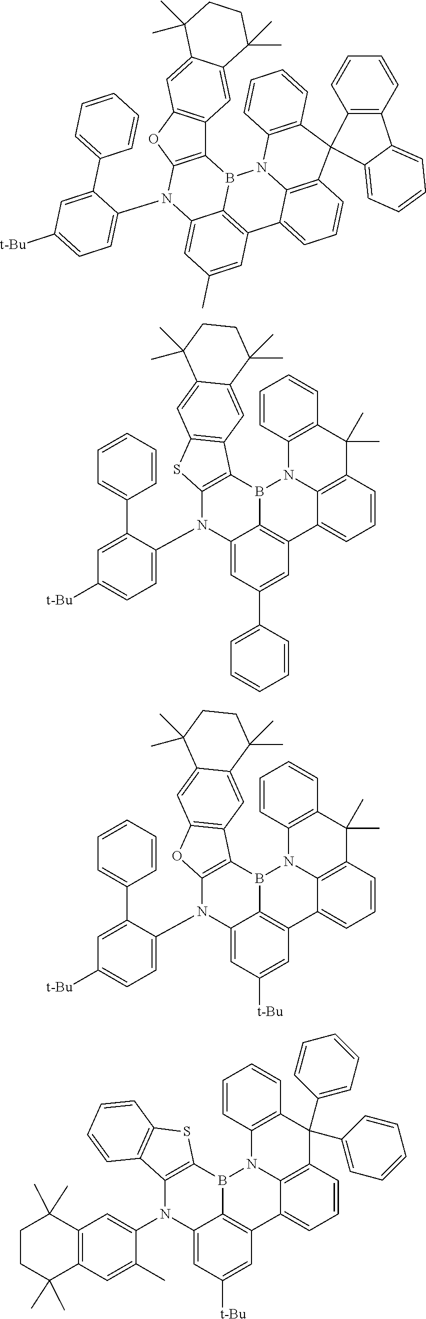 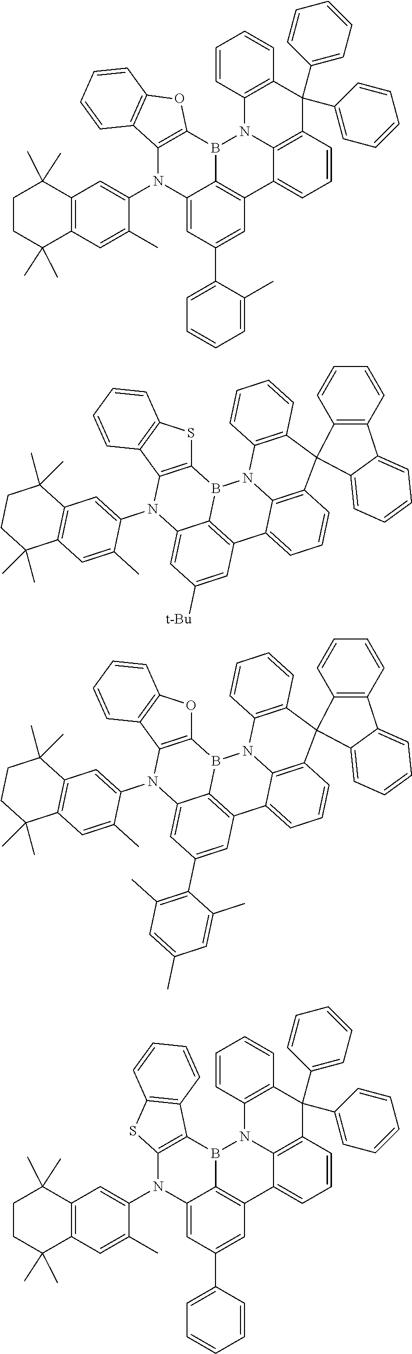 [SMILES: Cc1ccccc1-c1cc2c3c(c1)N(c1cc4c(cc1C)C(C)(C)CCC4(C)C)c1c(oc4ccccc14)B3N1c3ccccc3C(c3ccccc3)(c3ccccc3)c3cccc-2c31 ; Cc1cc2c(cc1N1c3cc(C(C)(C)C)cc4c3B(c3sc5ccccc5c31)N1c3ccccc3C3(c5ccccc5-c5ccccc53)c3cccc-4c31)C(C)(C)CCC2(C)C ; Cc1cc(C)c(-c2cc3c4c(c2)N(c2cc5c(cc2C)C(C)(C)CCC5(C)C)c2c(oc5ccccc25)B4N2c4ccccc4C4(c5ccccc5-c5ccccc54)c4cccc-3c42)c(C)c1 ; Cc1cc2c(cc1N1c3cc(-c4ccccc4)cc4c3B(c3c1sc1ccccc31)N1c3ccccc3C(c3ccccc3)(c3ccccc3)c3cccc-4c31)C(C)(C)CCC2(C)C] 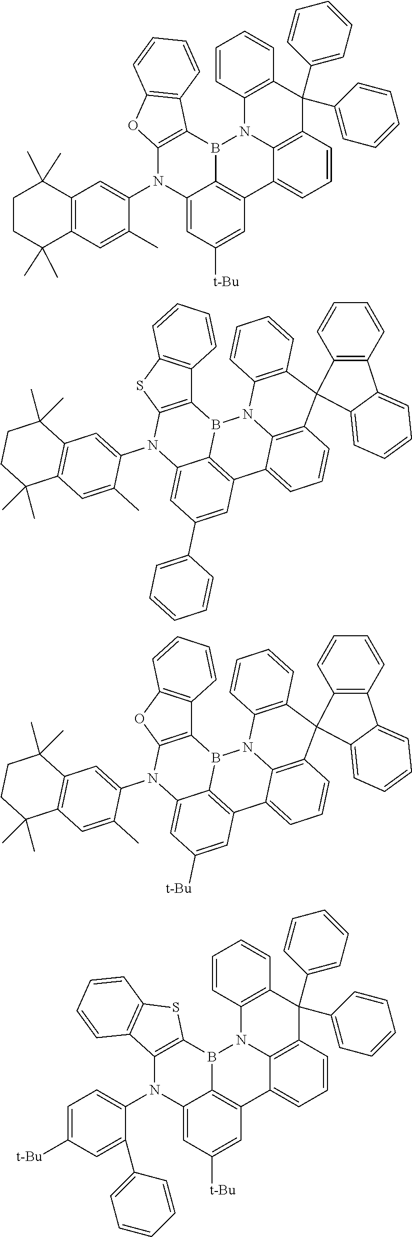 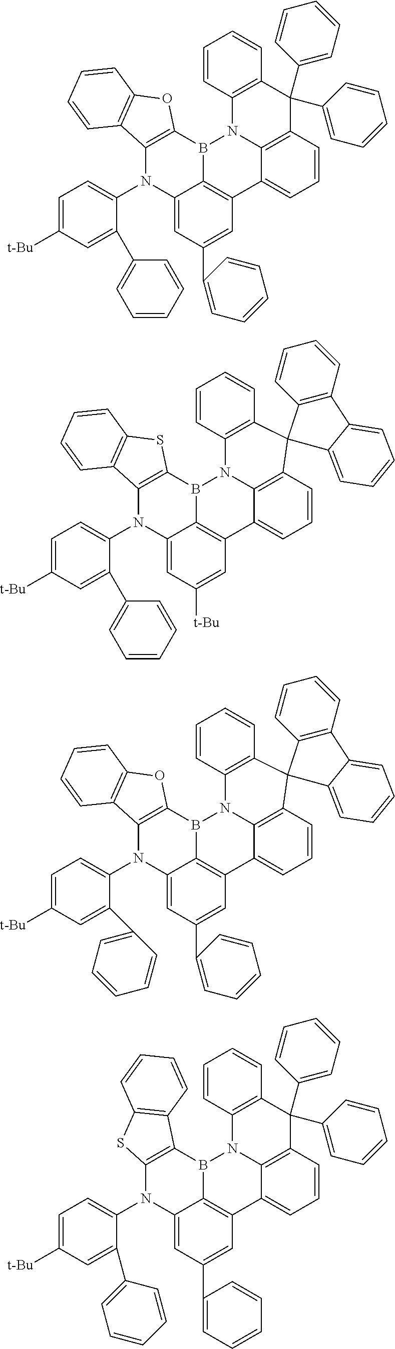 [SMILES: CC(C)(C)c1ccc(N2c3cc(-c4ccccc4)cc4c3B(c3oc5ccccc5c32)N2c3ccccc3C(c3ccccc3)(c3ccccc3)c3cccc-4c32)c(-c2ccccc2)c1 ; CC(C)(C)c1ccc(N2c3cc(C(C)(C)C)cc4c3B(c3sc5ccccc5c32)N2c3ccccc3C3(c5ccccc5-c5ccccc53)c3cccc-4c32)c(-c2ccccc2)c1 ; CC(C)(C)c1ccc(N2c3cc(-c4ccccc4)cc4c3B(c3oc5ccccc5c32)N2c3ccccc3C3(c5ccccc5-c5ccccc53)c3cccc-4c32)c(-c2ccccc2)c1 ; CC(C)(C)c1ccc(N2c3cc(-c4ccccc4)cc4c3B(c3c2sc2ccccc32)N2c3ccccc3C(c3ccccc3)(c3ccccc3)c3cccc-4c32)c(-c2ccccc2)c1] 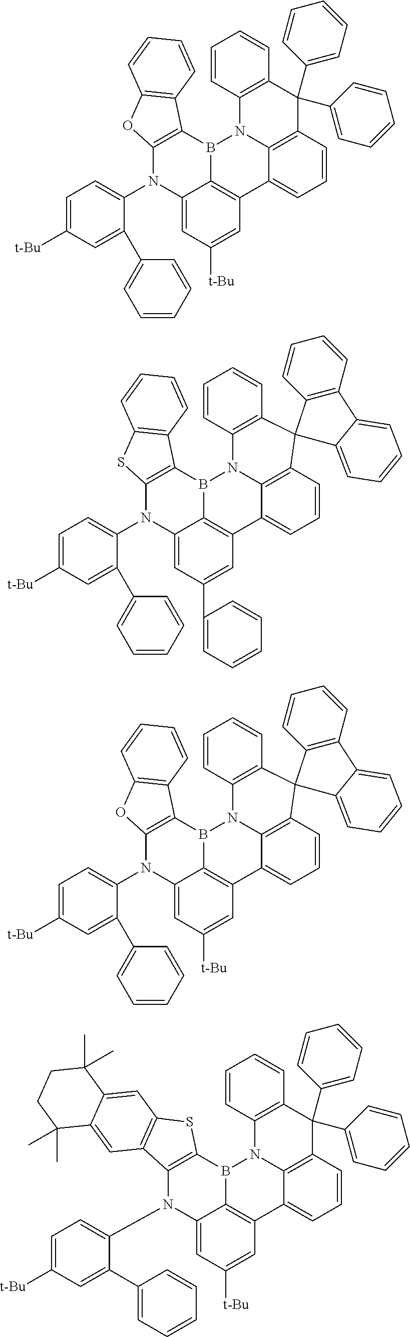 [SMILES: CC(C)(C)c1ccc(N2c3cc(C(C)(C)C)cc4c3B(c3c2oc2ccccc32)N2c3ccccc3C(c3ccccc3)(c3ccccc3)c3cccc-4c32)c(-c2ccccc2)c1 ; CC(C)(C)c1ccc(N2c3cc(-c4ccccc4)cc4c3B(c3c2sc2ccccc32)N2c3ccccc3C3(c5ccccc5-c5ccccc53)c3cccc-4c32)c(-c2ccccc2)c1 ; CC(C)(C)c1ccc(N2c3cc(C(C)(C)C)cc4c3B(c3c2oc2ccccc32)N2c3ccccc3C3(c5ccccc5-c5ccccc53)c3cccc-4c32)c(-c2ccccc2)c1 ; CC(C)(C)c1ccc(N2c3cc(C(C)(C)C)cc4c3B(c3sc5cc6c(cc5c32)C(C)(C)CCC6(C)C)N2c3ccccc3C(c3ccccc3)(c3ccccc3)c3cccc-4c32)c(-c2ccccc2)c1] 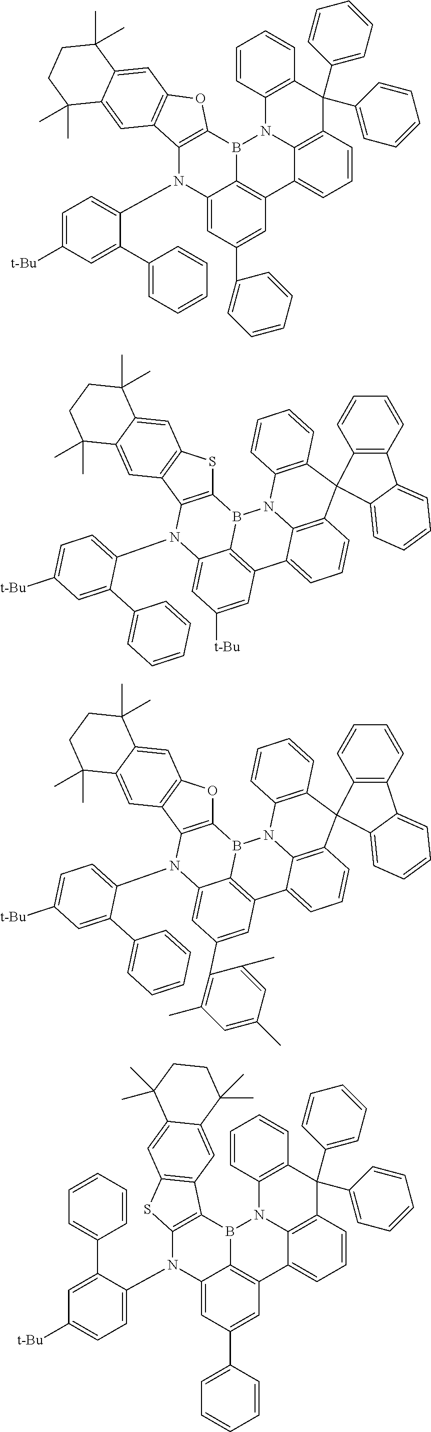 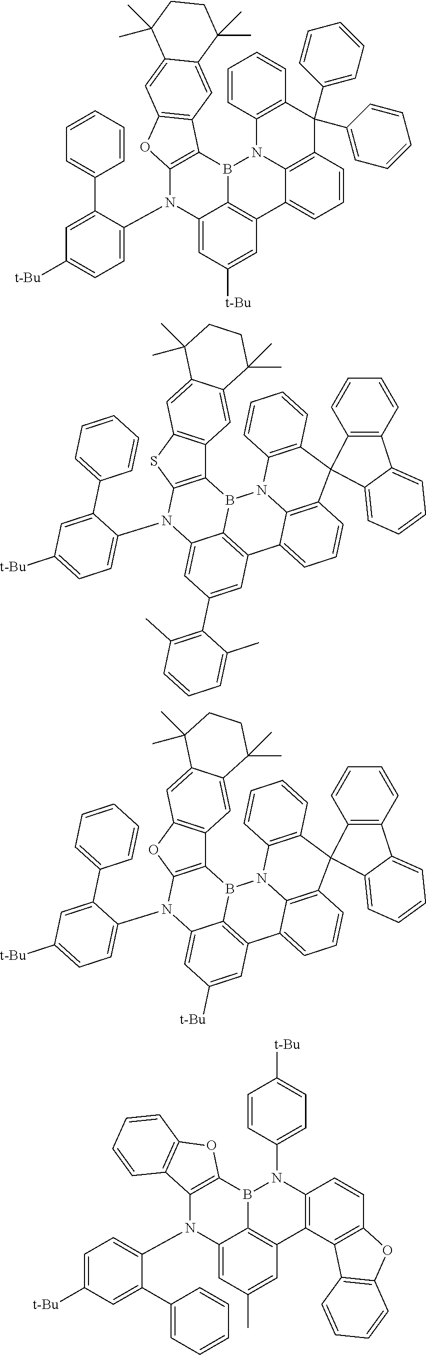 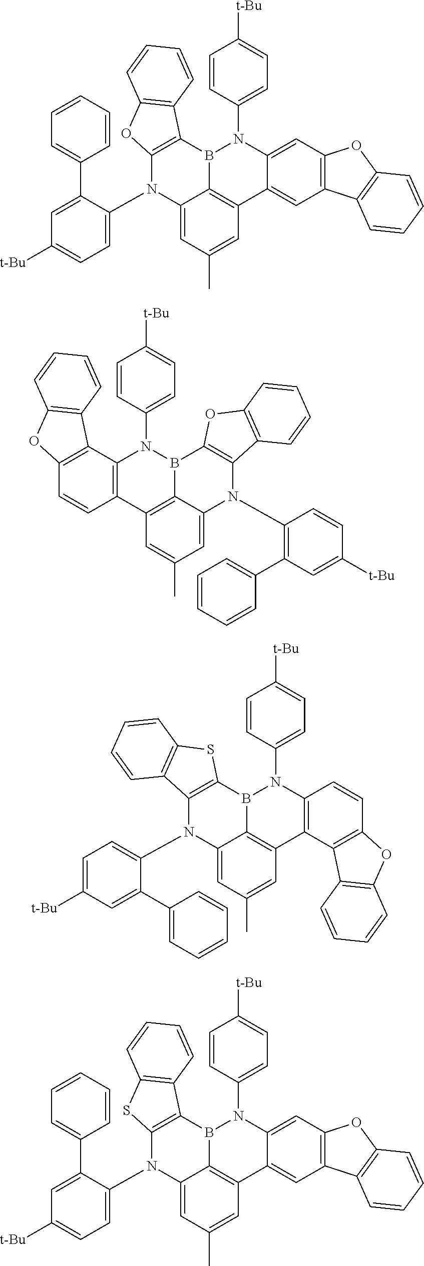 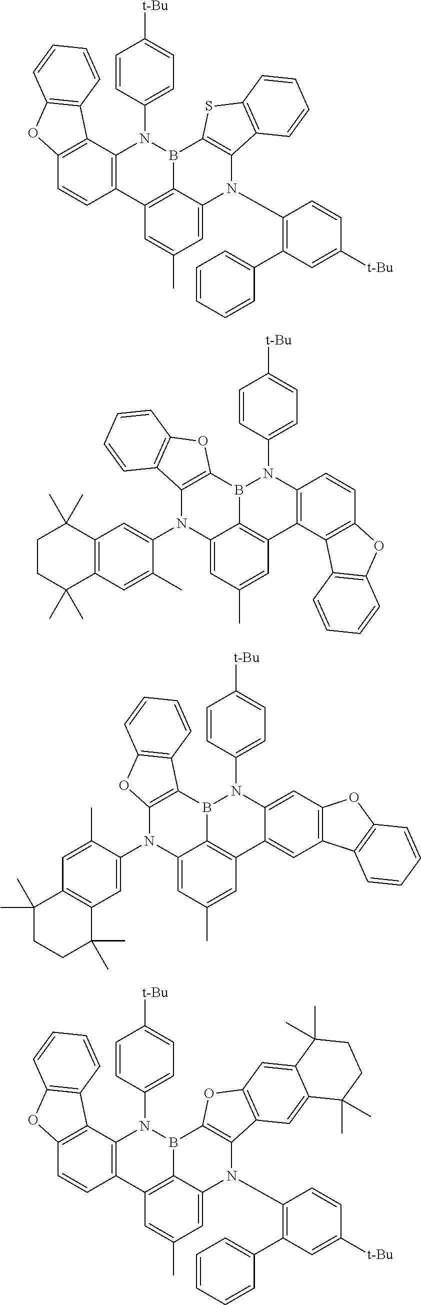 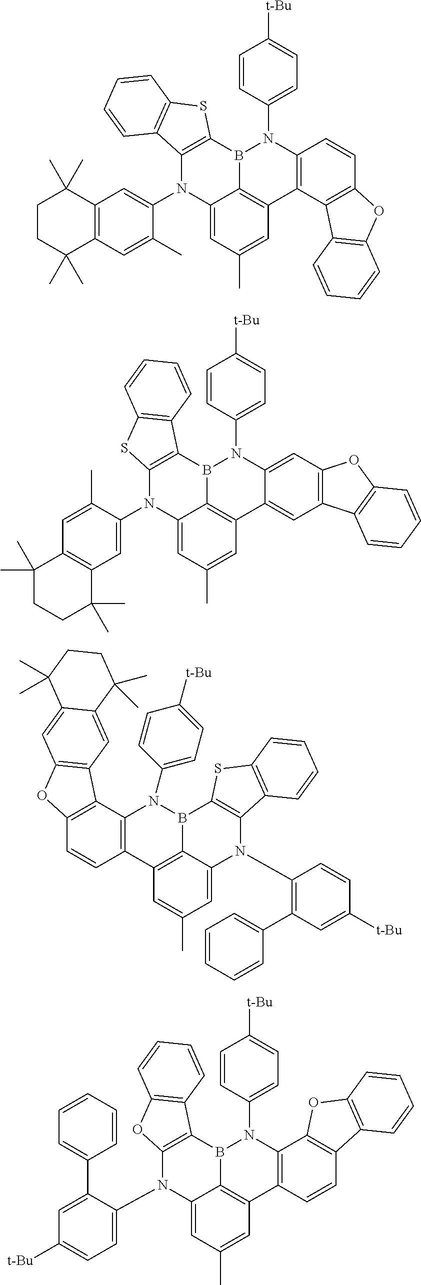 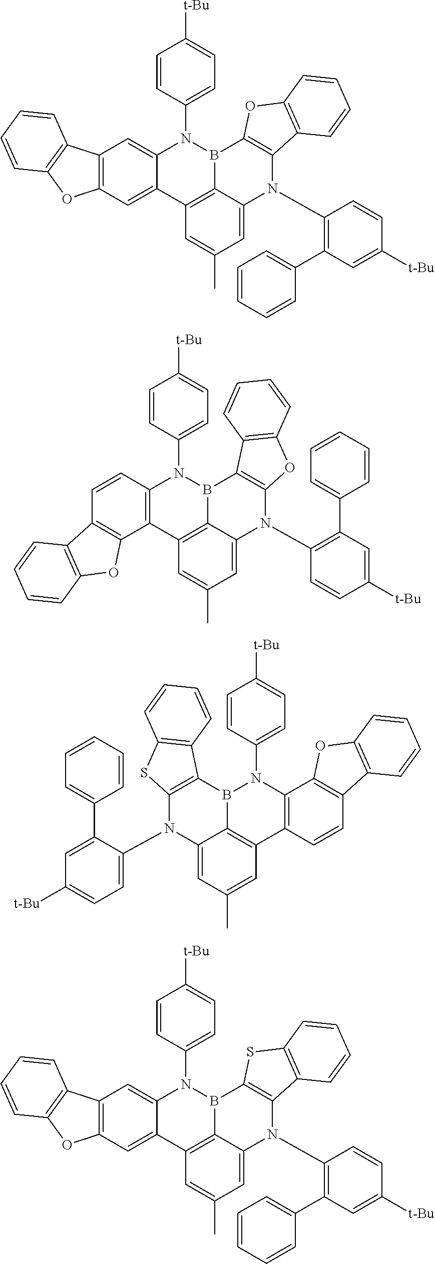 [SMILES: Cc1cc2c3c(c1)N(c1ccc(C(C)(C)C)cc1-c1ccccc1)c1c(oc4ccccc14)B3N(c1ccc(C(C)(C)C)cc1)c1cc3c(cc1-2)oc1ccccc13 ; Cc1cc2c3c(c1)N(c1ccc(C(C)(C)C)cc1-c1ccccc1)c1oc4ccccc4c1B3N(c1ccc(C(C)(C)C)cc1)c1ccc3c(oc4ccccc43)c1-2 ; Cc1cc2c3c(c1)N(c1ccc(C(C)(C)C)cc1-c1ccccc1)c1sc4ccccc4c1B3N(c1ccc(C(C)(C)C)cc1)c1c-2ccc2c1oc1ccccc12 ; Cc1cc2c3c(c1)N(c1ccc(C(C)(C)C)cc1-c1ccccc1)c1c(sc4ccccc14)B3N(c1ccc(C(C)(C)C)cc1)c1cc3c(cc1-2)oc1ccccc13] 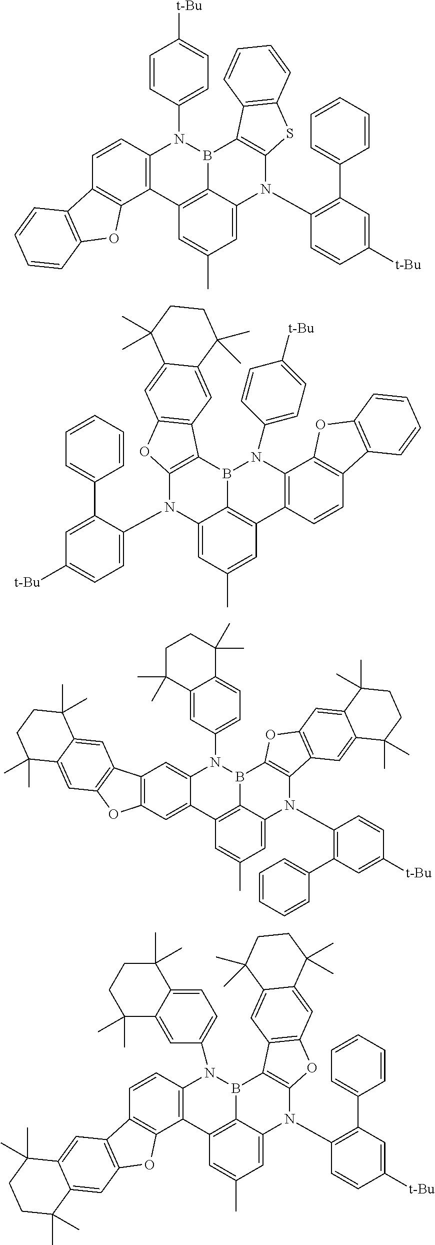 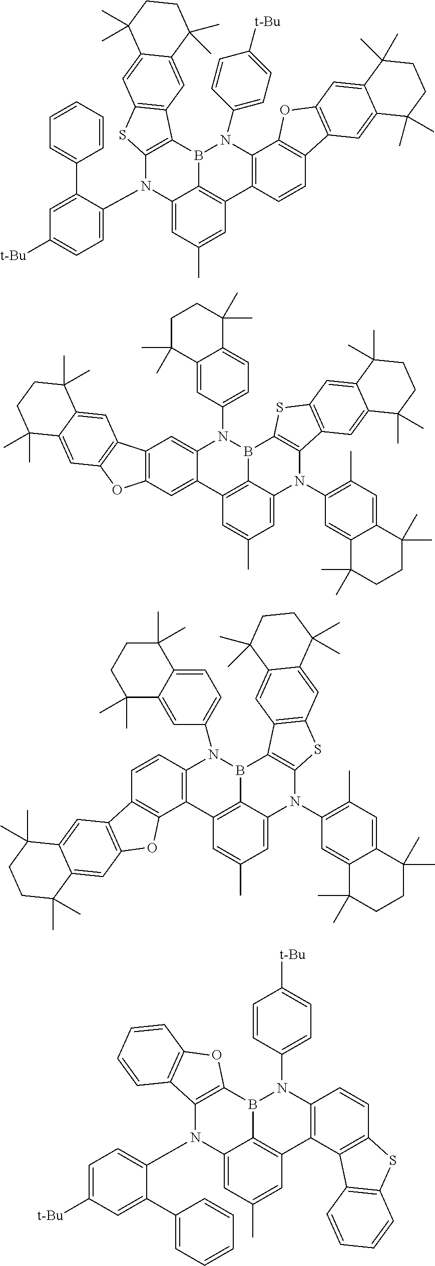 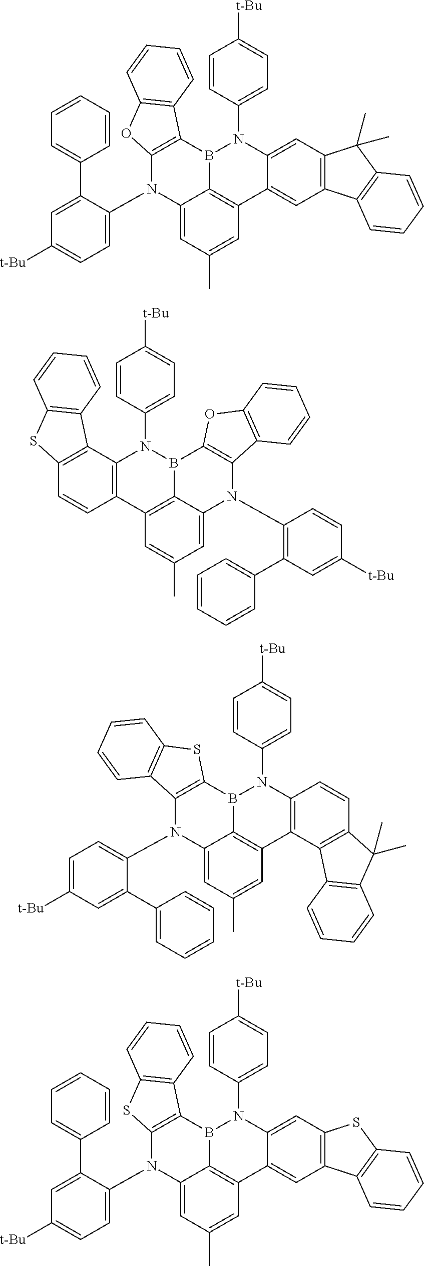 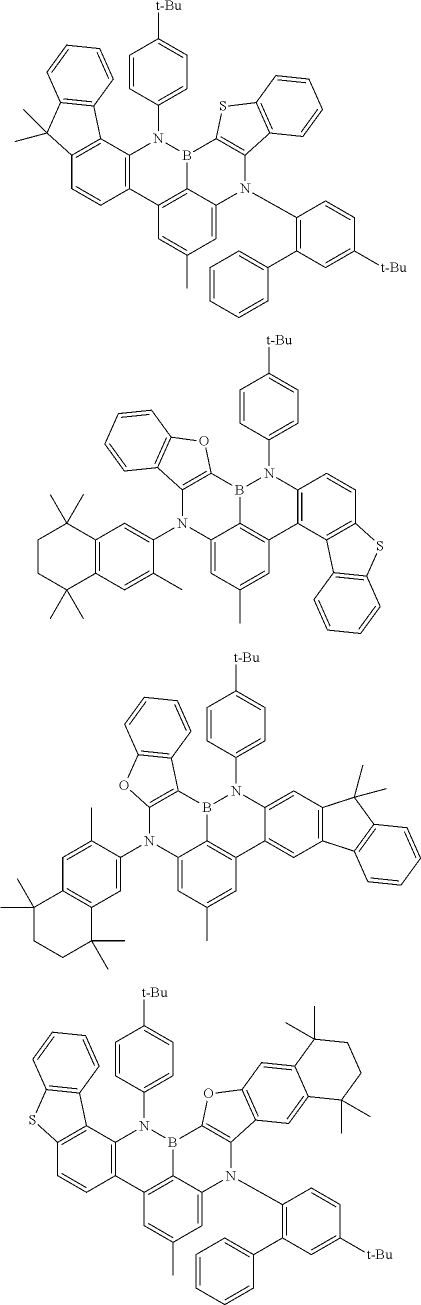 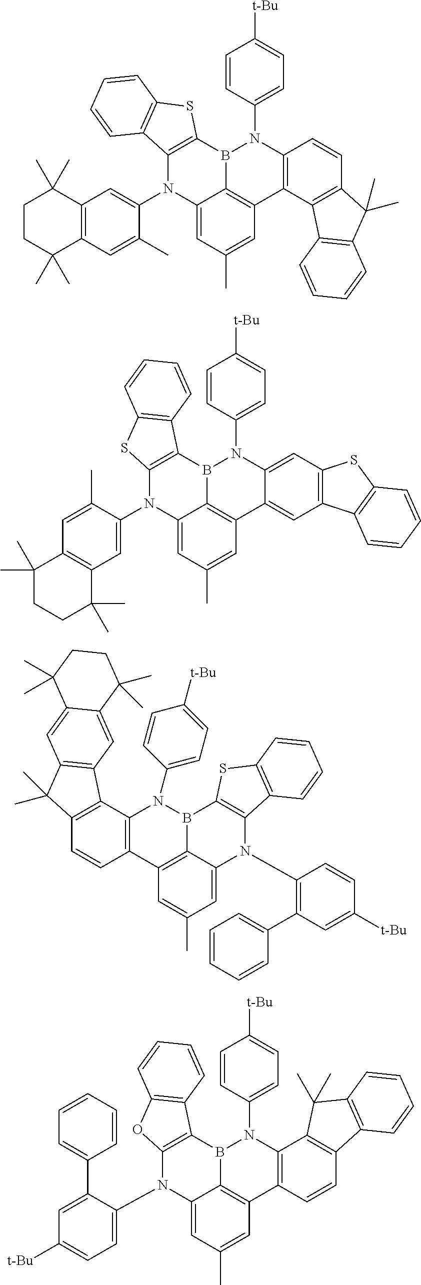 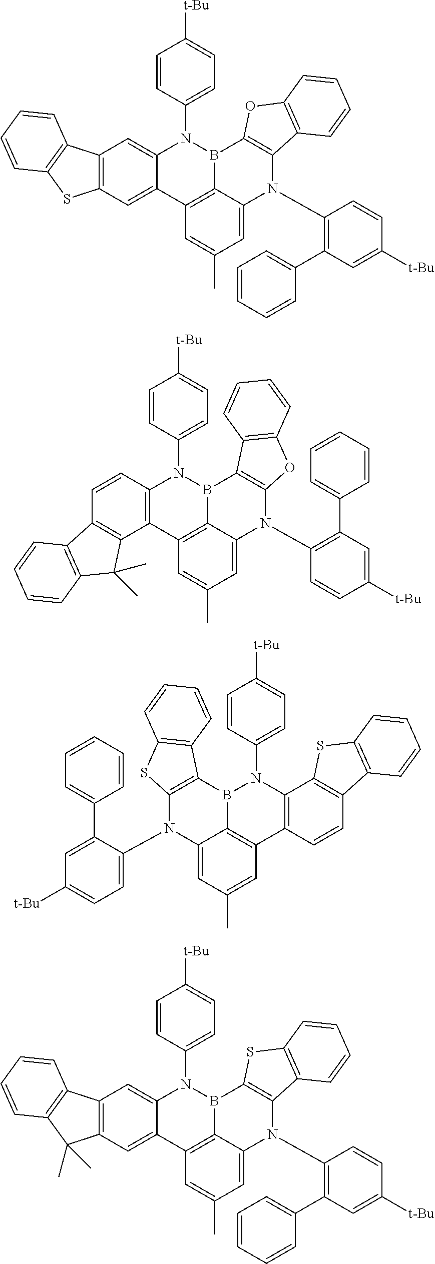 [SMILES: Cc1cc2c3c(c1)N(c1ccc(C(C)(C)C)cc1-c1ccccc1)c1c(oc4ccccc14)B3N(c1ccc(C(C)(C)C)cc1)c1cc3c(cc1-2)sc1ccccc13 ; Cc1cc2c3c(c1)N(c1ccc(C(C)(C)C)cc1-c1ccccc1)c1oc4ccccc4c1B3N(c1ccc(C(C)(C)C)cc1)c1ccc3c(c1-2)C(C)(C)c1ccccc1-3 ; Cc1cc2c3c(c1)N(c1ccc(C(C)(C)C)cc1-c1ccccc1)c1sc4ccccc4c1B3N(c1ccc(C(C)(C)C)cc1)c1c-2ccc2c1sc1ccccc12 ; Cc1cc2c3c(c1)N(c1ccc(C(C)(C)C)cc1-c1ccccc1)c1c(sc4ccccc14)B3N(c1ccc(C(C)(C)C)cc1)c1cc3c(cc1-2)C(C)(C)c1ccccc1-3] 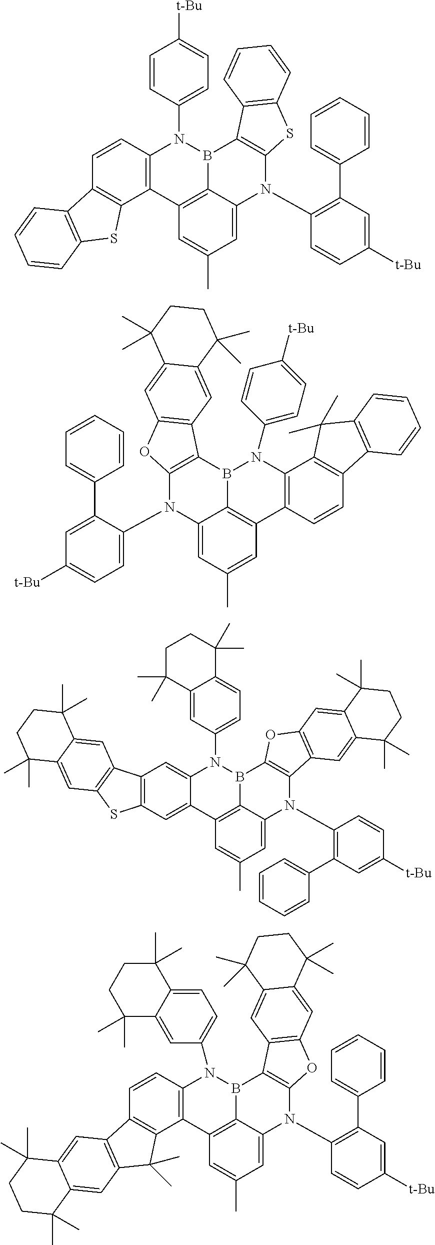 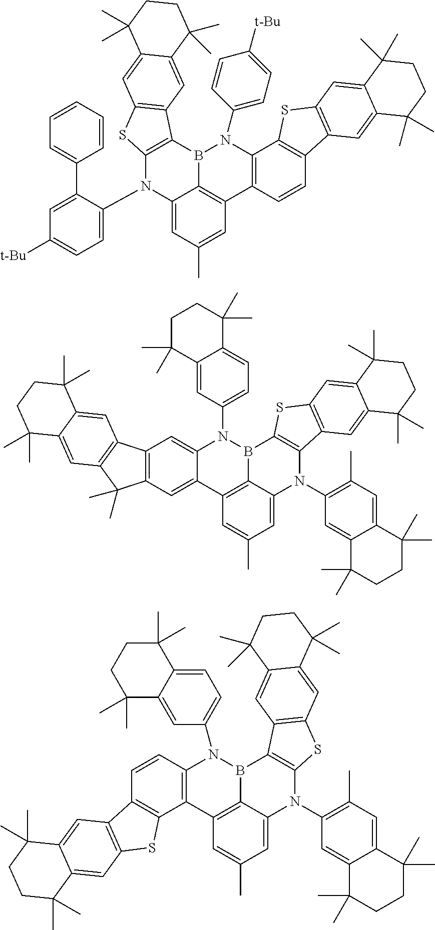 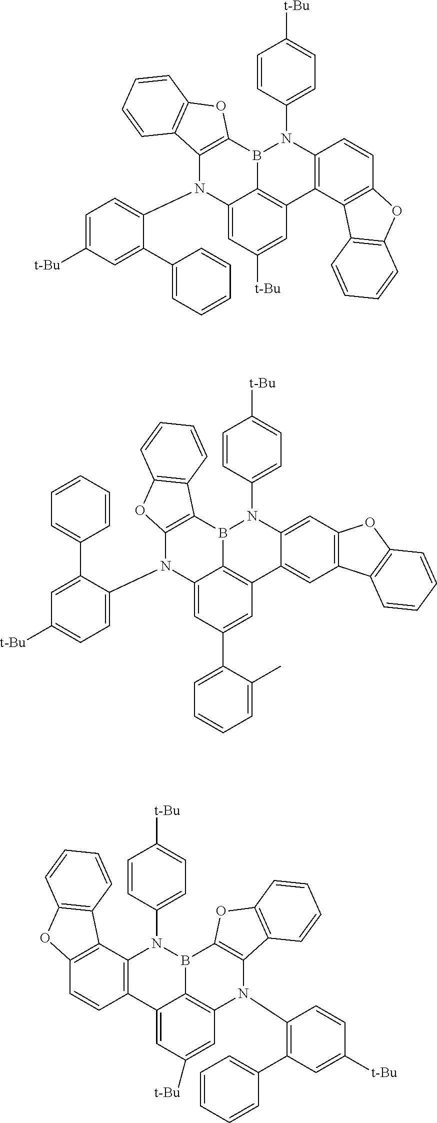 [SMILES: CC(C)(C)c1ccc(N2B3c4oc5ccccc5c4N(c4ccc(C(C)(C)C)cc4-c4ccccc4)c4cc(C(C)(C)C)cc(c43)-c3c2ccc2oc4ccccc4c32)cc1 ; Cc1ccccc1-c1cc2c3c(c1)N(c1ccc(C(C)(C)C)cc1-c1ccccc1)c1oc4ccccc4c1B3N(c1ccc(C(C)(C)C)cc1)c1cc3oc4ccccc4c3cc1-2 ; CC(C)(C)c1ccc(N2B3c4oc5ccccc5c4N(c4ccc(C(C)(C)C)cc4-c4ccccc4)c4cc(C(C)(C)C)cc(c43)-c3ccc4oc5ccccc5c4c32)cc1] 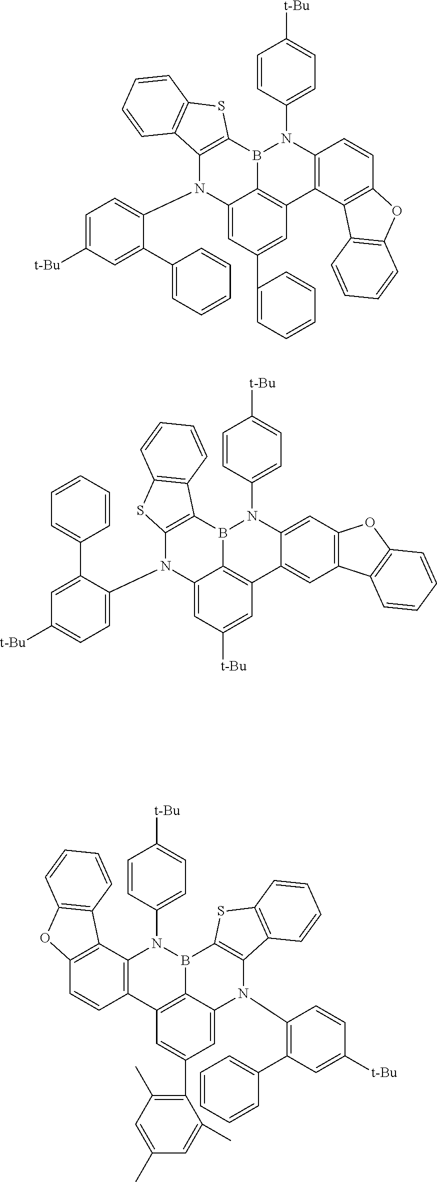 [SMILES: CC(C)(C)c1ccc(N2B3c4sc5ccccc5c4N(c4ccc(C(C)(C)C)cc4-c4ccccc4)c4cc(-c5ccccc5)cc(c43)-c3c2ccc2oc4ccccc4c32)cc1 ; CC(C)(C)c1ccc(N2B3c4c(cc(C(C)(C)C)cc4N(c4ccc(C(C)(C)C)cc4-c4ccccc4)c4sc5ccccc5c43)-c3cc4c(cc32)oc2ccccc24)cc1 ; Cc1cc(C)c(-c2cc3c4c(c2)N(c2ccc(C(C)(C)C)cc2-c2ccccc2)c2c(sc5ccccc25)B4N(c2ccc(C(C)(C)C)cc2)c2c-3ccc3oc4ccccc4c23)c(C)c1] 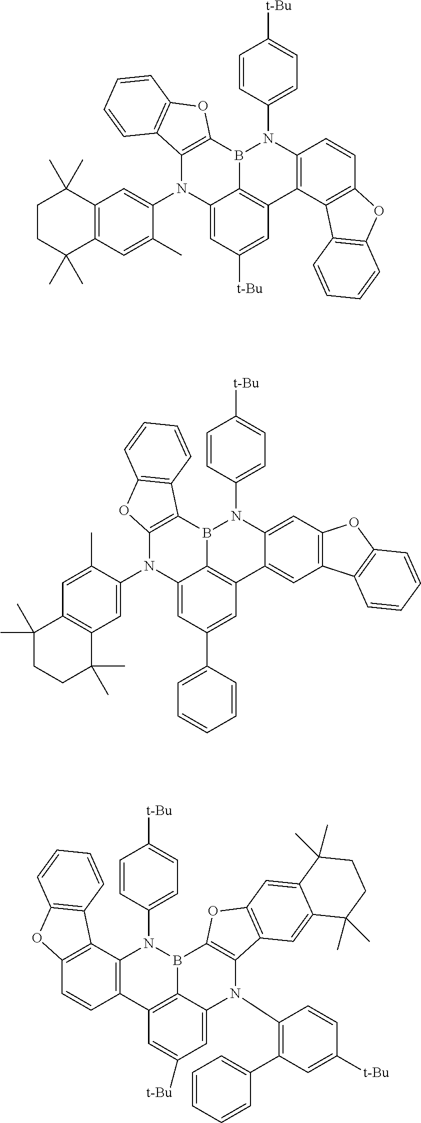 [SMILES: Cc1cc2c(cc1N1c3cc(C(C)(C)C)cc4c3B(c3oc5ccccc5c31)N(c1ccc(C(C)(C)C)cc1)c1ccc3oc5ccccc5c3c1-4)C(C)(C)CCC2(C)C ; Cc1cc2c(cc1N1c3cc(-c4ccccc4)cc4c3B(c3c1oc1ccccc31)N(c1ccc(C(C)(C)C)cc1)c1cc3oc5ccccc5c3cc1-4)C(C)(C)CCC2(C)C ; CC(C)(C)c1ccc(N2B3c4oc5cc6c(cc5c4N(c4ccc(C(C)(C)C)cc4-c4ccccc4)c4cc(C(C)(C)C)cc(c43)-c3ccc4oc5ccccc5c4c32)C(C)(C)CCC6(C)C)cc1] 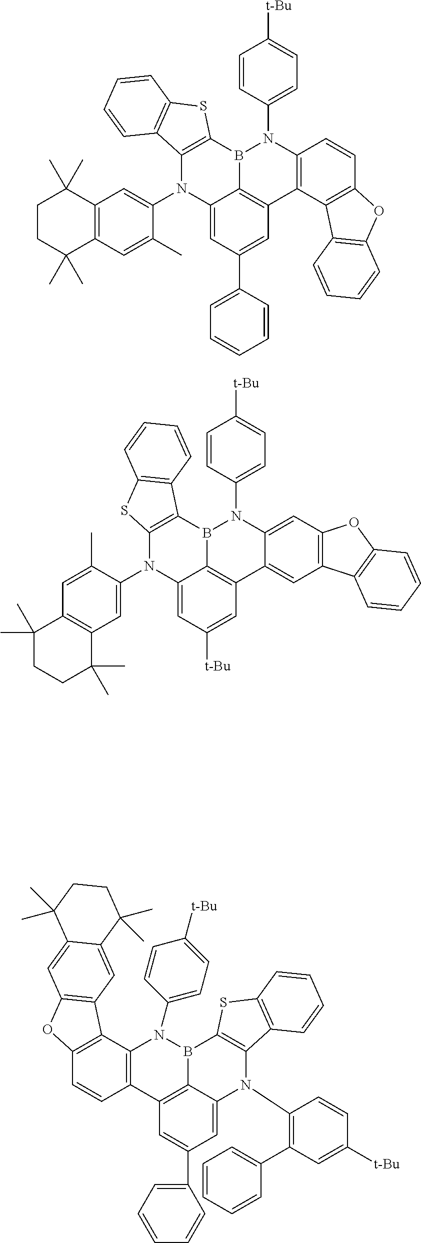 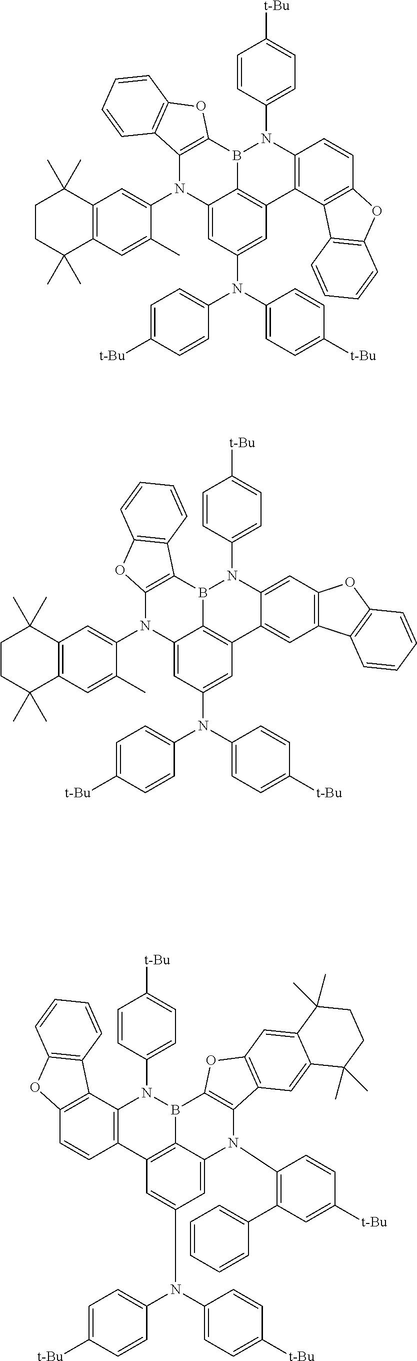 [SMILES: Cc1cc2c(cc1N1c3cc(N(c4ccc(C(C)(C)C)cc4)c4ccc(C(C)(C)C)cc4)cc4c3B(c3oc5ccccc5c31)N(c1ccc(C(C)(C)C)cc1)c1ccc3oc5ccccc5c3c1-4)C(C)(C)CCC2(C)C ; Cc1cc2c(cc1N1c3cc(N(c4ccc(C(C)(C)C)cc4)c4ccc(C(C)(C)C)cc4)cc4c3B(c3c1oc1ccccc31)N(c1ccc(C(C)(C)C)cc1)c1cc3oc5ccccc5c3cc1-4)C(C)(C)CCC2(C)C ; CC(C)(C)c1ccc(N2B3c4oc5cc6c(cc5c4N(c4ccc(C(C)(C)C)cc4-c4ccccc4)c4cc(N(c5ccc(C(C)(C)C)cc5)c5ccc(C(C)(C)C)cc5)cc(c43)-c3ccc4oc5ccccc5c4c32)C(C)(C)CCC6(C)C)cc1] 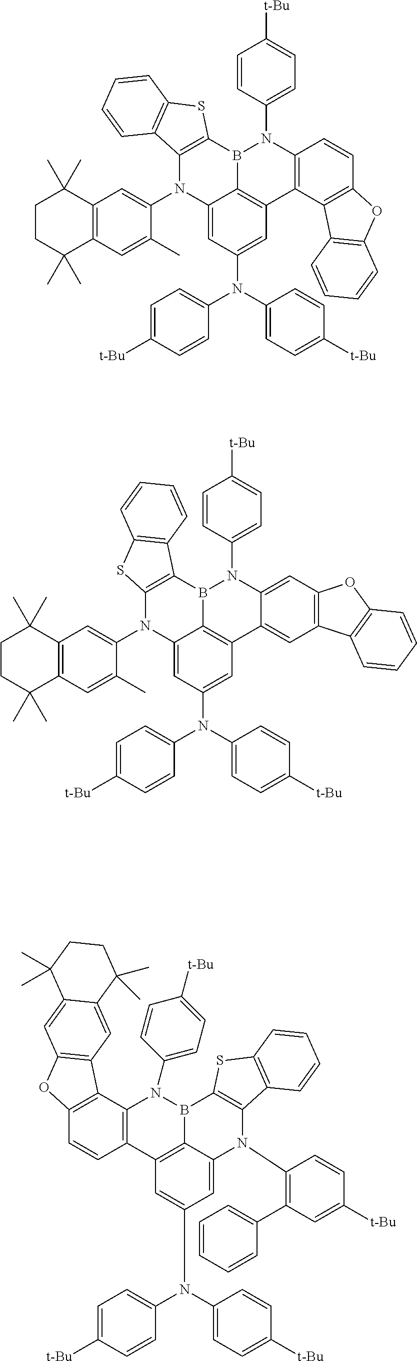 [SMILES: Cc1cc2c(cc1N1c3cc(N(c4ccc(C(C)(C)C)cc4)c4ccc(C(C)(C)C)cc4)cc4c3B(c3sc5ccccc5c31)N(c1ccc(C(C)(C)C)cc1)c1ccc3oc5ccccc5c3c1-4)C(C)(C)CCC2(C)C ; Cc1cc2c(cc1N1c3cc(N(c4ccc(C(C)(C)C)cc4)c4ccc(C(C)(C)C)cc4)cc4c3B(c3c1sc1ccccc31)N(c1ccc(C(C)(C)C)cc1)c1cc3oc5ccccc5c3cc1-4)C(C)(C)CCC2(C)C ; CC(C)(C)c1ccc(N2B3c4sc5ccccc5c4N(c4ccc(C(C)(C)C)cc4-c4ccccc4)c4cc(N(c5ccc(C(C)(C)C)cc5)c5ccc(C(C)(C)C)cc5)cc(c43)-c3ccc4oc5cc6c(cc5c4c32)C(C)(C)CCC6(C)C)cc1] 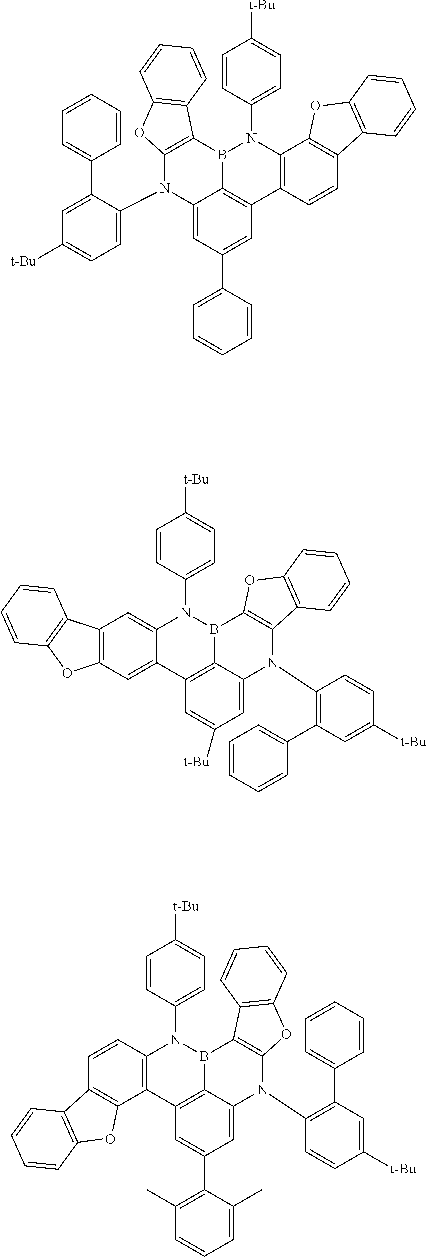 [SMILES: CC(C)(C)c1ccc(N2B3c4c(cc(-c5ccccc5)cc4N(c4ccc(C(C)(C)C)cc4-c4ccccc4)c4oc5ccccc5c43)-c3ccc4c(oc5ccccc54)c32)cc1 ; CC(C)(C)c1ccc(N2B3c4oc5ccccc5c4N(c4ccc(C(C)(C)C)cc4-c4ccccc4)c4cc(C(C)(C)C)cc(c43)-c3cc4oc5ccccc5c4cc32)cc1 ; Cc1cccc(C)c1-c1cc2c3c(c1)N(c1ccc(C(C)(C)C)cc1-c1ccccc1)c1oc4ccccc4c1B3N(c1ccc(C(C)(C)C)cc1)c1ccc3c(oc4ccccc43)c1-2] 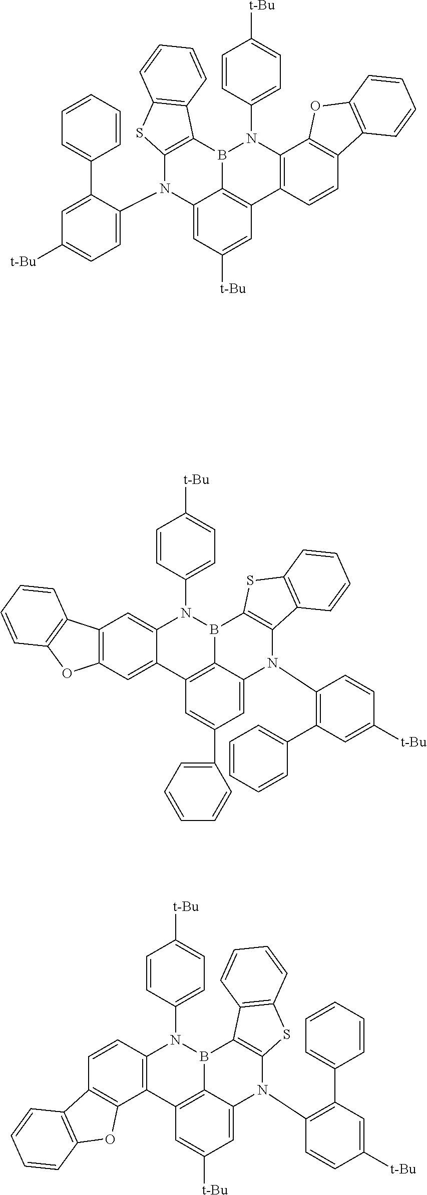 [SMILES: CC(C)(C)c1ccc(N2B3c4c(cc(C(C)(C)C)cc4N(c4ccc(C(C)(C)C)cc4-c4ccccc4)c4sc5ccccc5c43)-c3ccc4c(oc5ccccc54)c32)cc1 ; CC(C)(C)c1ccc(N2B3c4sc5ccccc5c4N(c4ccc(C(C)(C)C)cc4-c4ccccc4)c4cc(-c5ccccc5)cc(c43)-c3cc4oc5ccccc5c4cc32)cc1 ; CC(C)(C)c1ccc(N2B3c4c(cc(C(C)(C)C)cc4N(c4ccc(C(C)(C)C)cc4-c4ccccc4)c4sc5ccccc5c43)-c3c2ccc2c3oc3ccccc32)cc1] 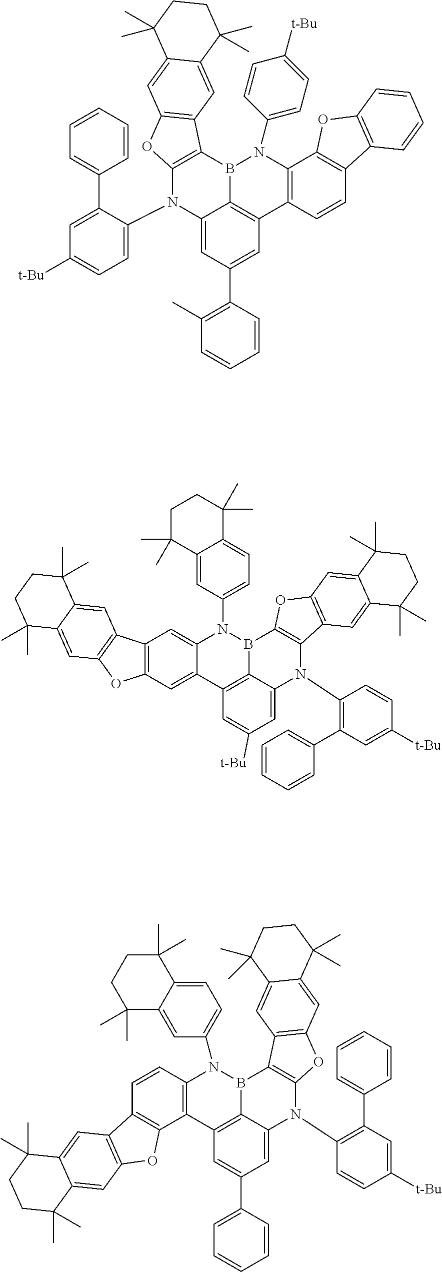 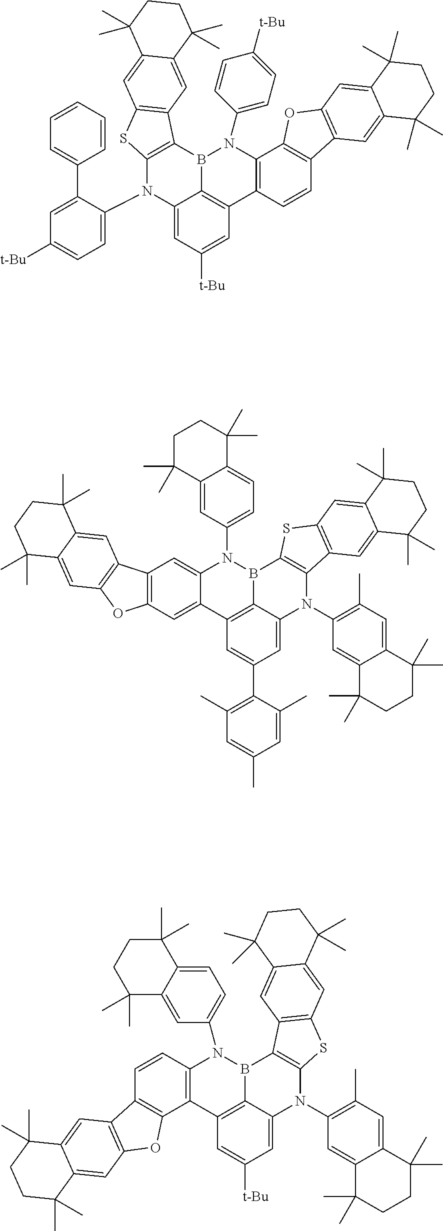 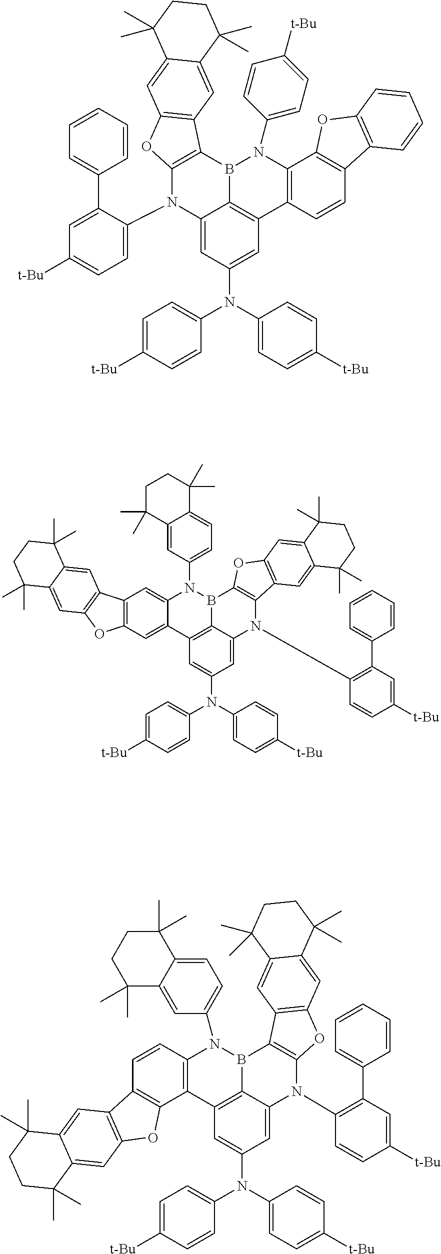 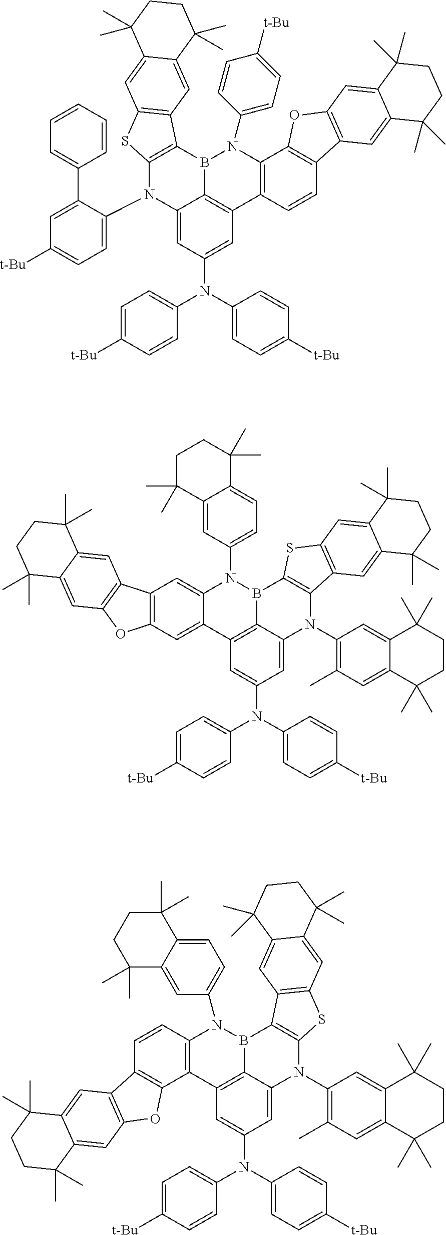 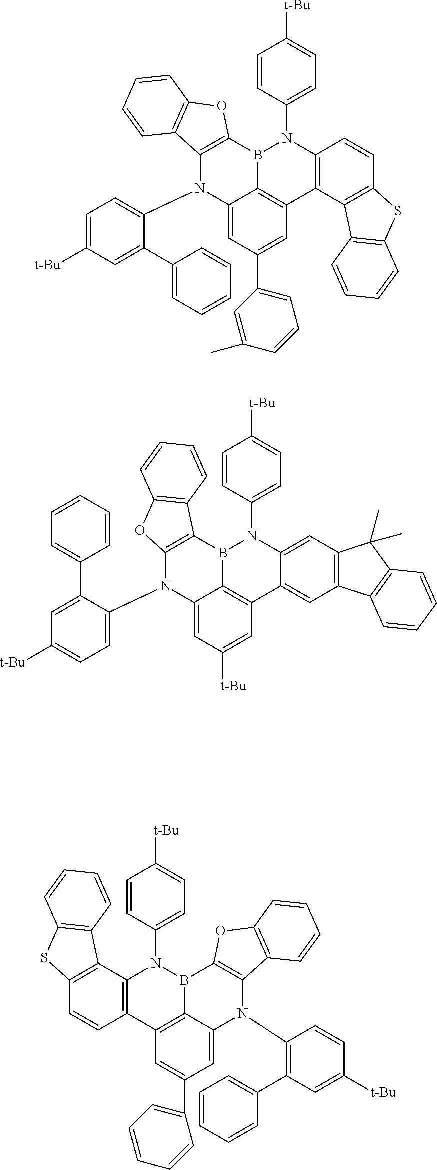 [SMILES: Cc1cccc(-c2cc3c4c(c2)N(c2ccc(C(C)(C)C)cc2-c2ccccc2)c2c(oc5ccccc25)B4N(c2ccc(C(C)(C)C)cc2)c2ccc4sc5ccccc5c4c2-3)c1 ; CC(C)(C)c1ccc(N2B3c4c(cc(C(C)(C)C)cc4N(c4ccc(C(C)(C)C)cc4-c4ccccc4)c4oc5ccccc5c43)-c3cc4c(cc32)C(C)(C)c2ccccc2-4)cc1 ; CC(C)(C)c1ccc(N2B3c4oc5ccccc5c4N(c4ccc(C(C)(C)C)cc4-c4ccccc4)c4cc(-c5ccccc5)cc(c43)-c3ccc4sc5ccccc5c4c32)cc1] 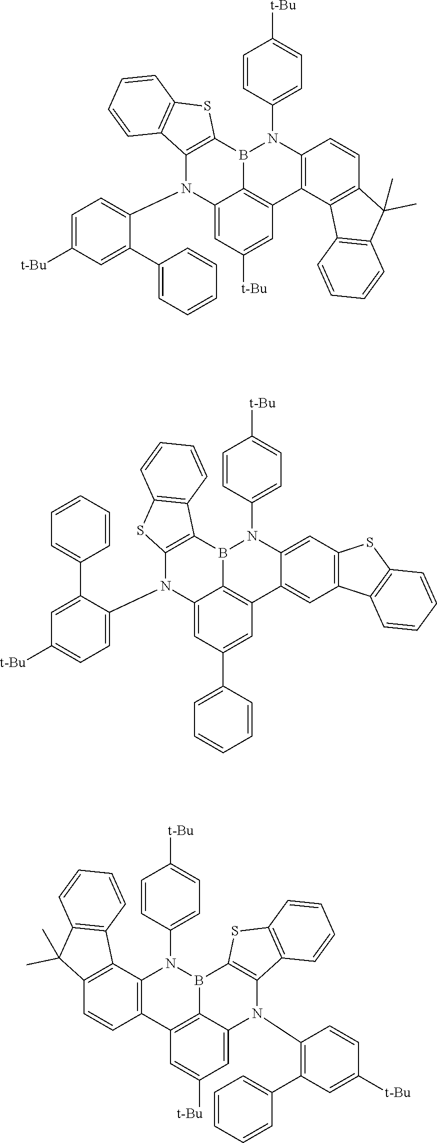 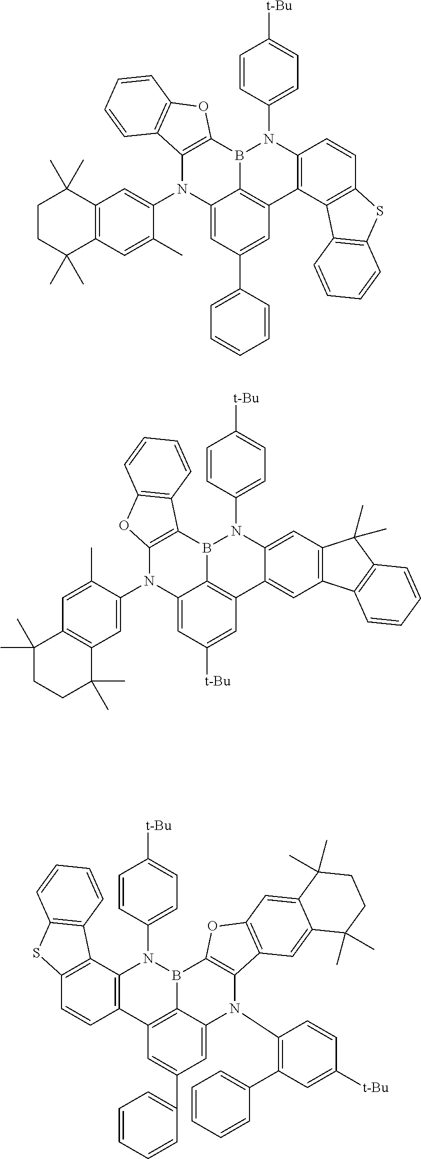 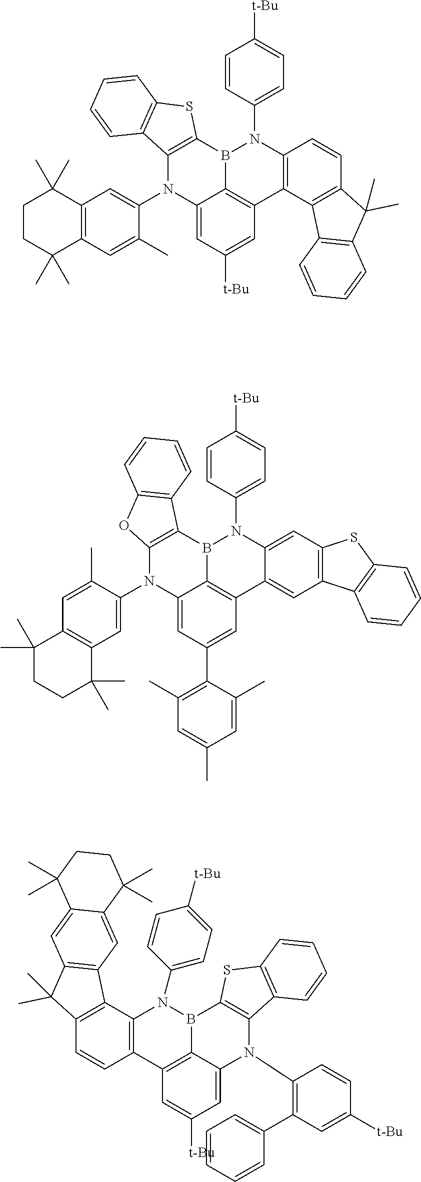 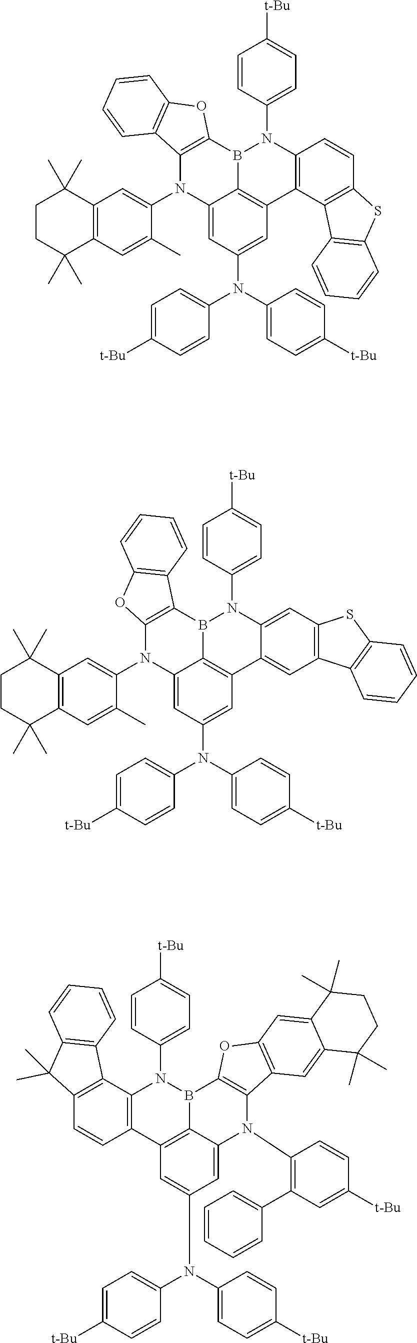 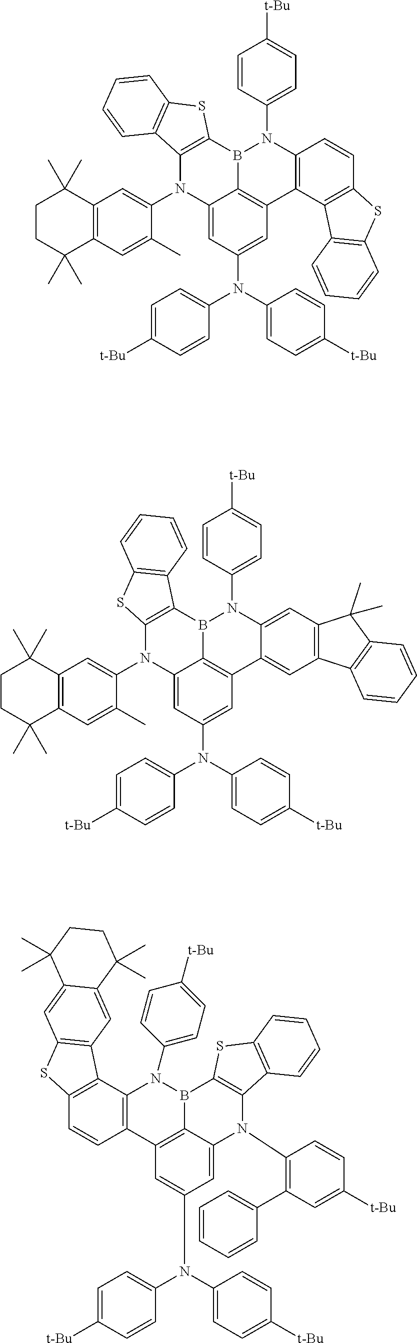 [SMILES: Cc1cc2c(cc1N1c3cc(N(c4ccc(C(C)(C)C)cc4)c4ccc(C(C)(C)C)cc4)cc4c3B(c3sc5ccccc5c31)N(c1ccc(C(C)(C)C)cc1)c1ccc3sc5ccccc5c3c1-4)C(C)(C)CCC2(C)C ; Cc1cc2c(cc1N1c3cc(N(c4ccc(C(C)(C)C)cc4)c4ccc(C(C)(C)C)cc4)cc4c3B(c3c1sc1ccccc31)N(c1ccc(C(C)(C)C)cc1)c1cc3c(cc1-4)-c1ccccc1C3(C)C)C(C)(C)CCC2(C)C ; CC(C)(C)c1ccc(N2B3c4sc5ccccc5c4N(c4ccc(C(C)(C)C)cc4-c4ccccc4)c4cc(N(c5ccc(C(C)(C)C)cc5)c5ccc(C(C)(C)C)cc5)cc(c43)-c3ccc4sc5cc6c(cc5c4c32)C(C)(C)CCC6(C)C)cc1] 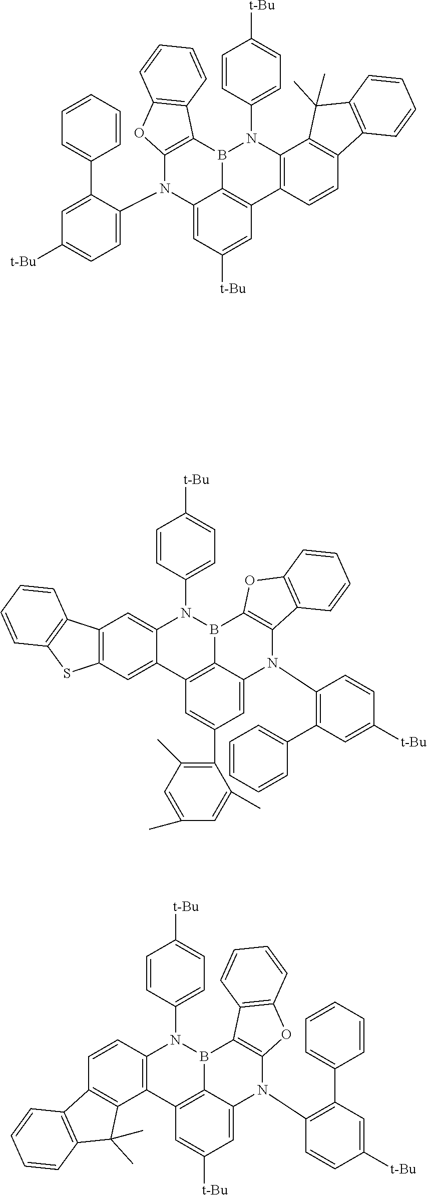 [SMILES: CC(C)(C)c1ccc(N2B3c4c(cc(C(C)(C)C)cc4N(c4ccc(C(C)(C)C)cc4-c4ccccc4)c4oc5ccccc5c43)-c3ccc4c(c32)C(C)(C)c2ccccc2-4)cc1 ; Cc1cc(C)c(-c2cc3c4c(c2)N(c2ccc(C(C)(C)C)cc2-c2ccccc2)c2c(oc5ccccc25)B4N(c2ccc(C(C)(C)C)cc2)c2cc4c(cc2-3)sc2ccccc24)c(C)c1 ; CC(C)(C)c1ccc(N2B3c4c(cc(C(C)(C)C)cc4N(c4ccc(C(C)(C)C)cc4-c4ccccc4)c4oc5ccccc5c43)-c3c2ccc2c3C(C)(C)c3ccccc3-2)cc1] 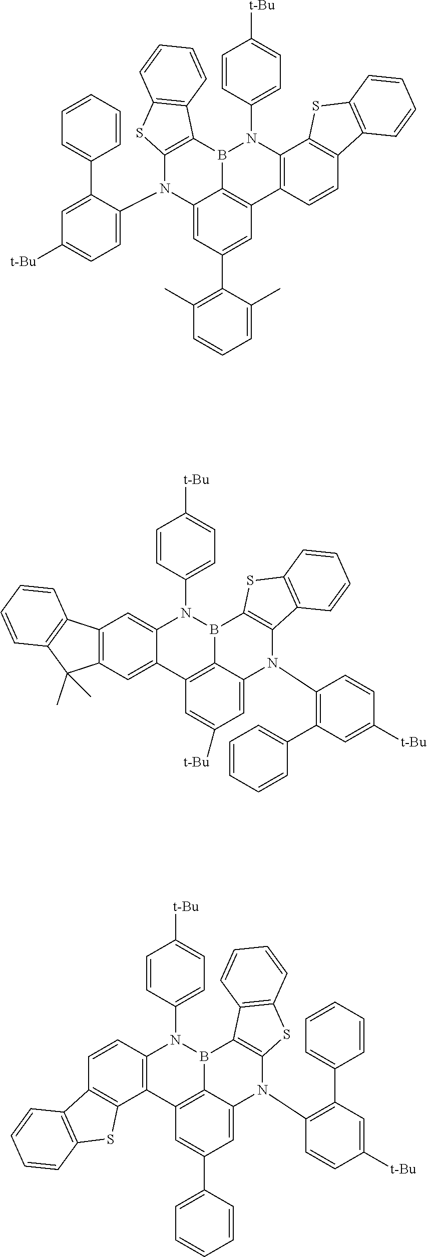 [SMILES: Cc1cccc(C)c1-c1cc2c3c(c1)N(c1ccc(C(C)(C)C)cc1-c1ccccc1)c1sc4ccccc4c1B3N(c1ccc(C(C)(C)C)cc1)c1c-2ccc2c1sc1ccccc12 ; CC(C)(C)c1ccc(N2B3c4sc5ccccc5c4N(c4ccc(C(C)(C)C)cc4-c4ccccc4)c4cc(C(C)(C)C)cc(c43)-c3cc4c(cc32)-c2ccccc2C4(C)C)cc1 ; CC(C)(C)c1ccc(N2B3c4c(cc(-c5ccccc5)cc4N(c4ccc(C(C)(C)C)cc4-c4ccccc4)c4sc5ccccc5c43)-c3c2ccc2c3sc3ccccc32)cc1] 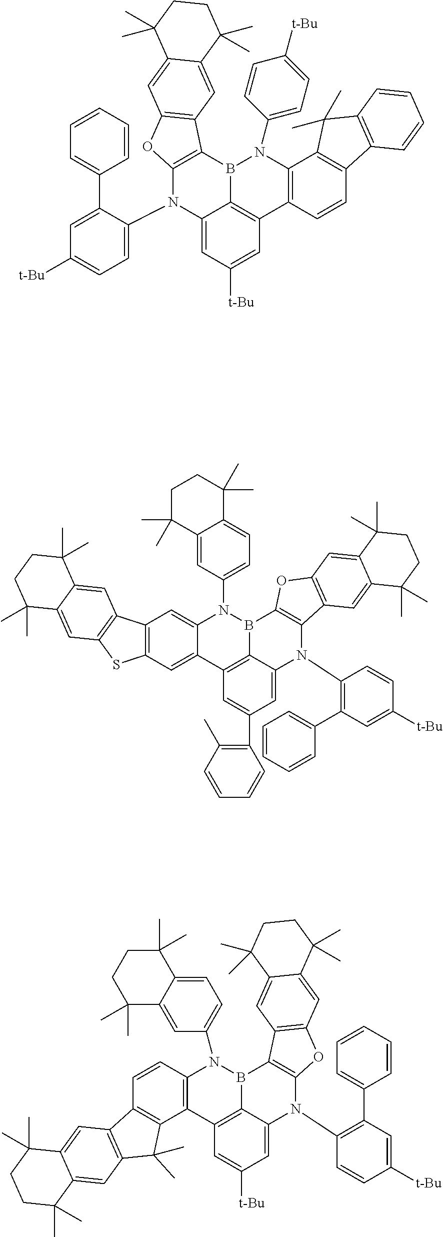 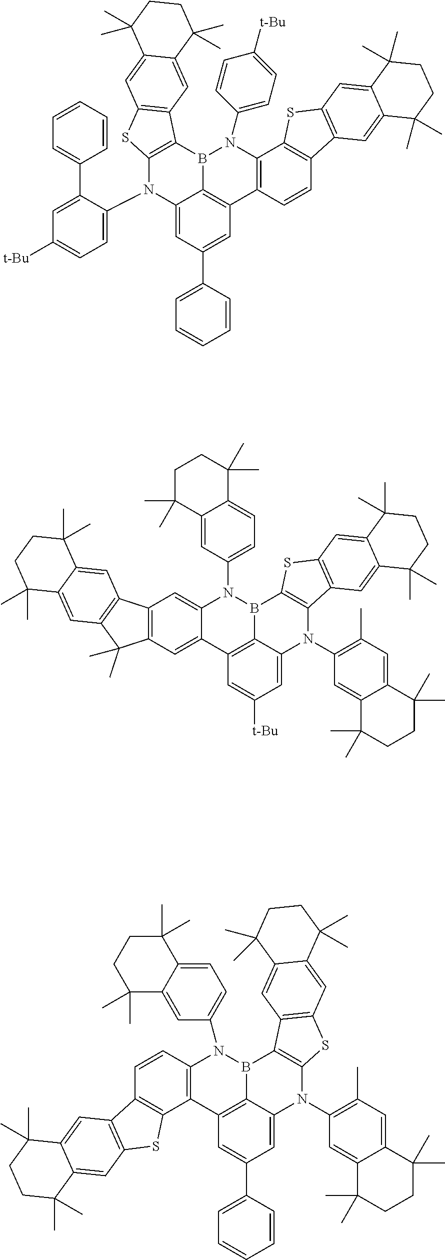 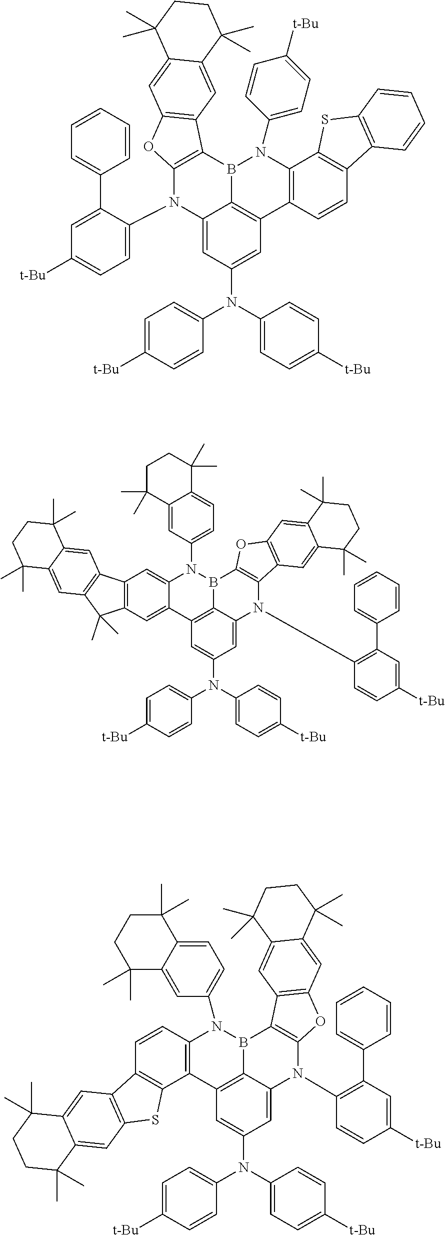 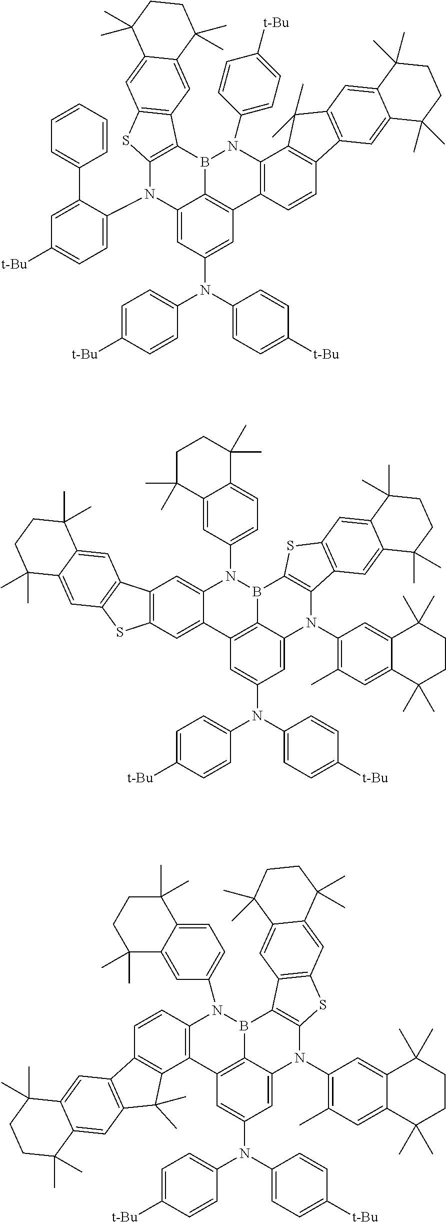 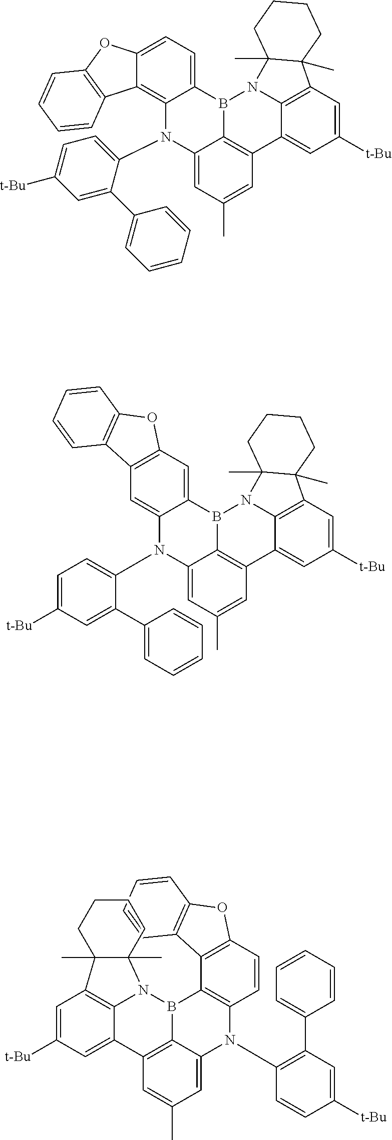 [SMILES: Cc1cc2c3c(c1)N(c1ccc(C(C)(C)C)cc1-c1ccccc1)c1c(ccc4oc5ccccc5c14)B3N1c3c-2cc(C(C)(C)C)cc3C2(C)CCCCC12C ; Cc1cc2c3c(c1)N(c1ccc(C(C)(C)C)cc1-c1ccccc1)c1cc4c(cc1B3N1c3c-2cc(C(C)(C)C)cc3C2(C)CCCCC12C)oc1ccccc14 ; Cc1cc2c3c(c1)N(c1ccc(C(C)(C)C)cc1-c1ccccc1)c1ccc4oc5ccccc5c4c1B3N1c3c-2cc(C(C)(C)C)cc3C2(C)CCCCC12C] 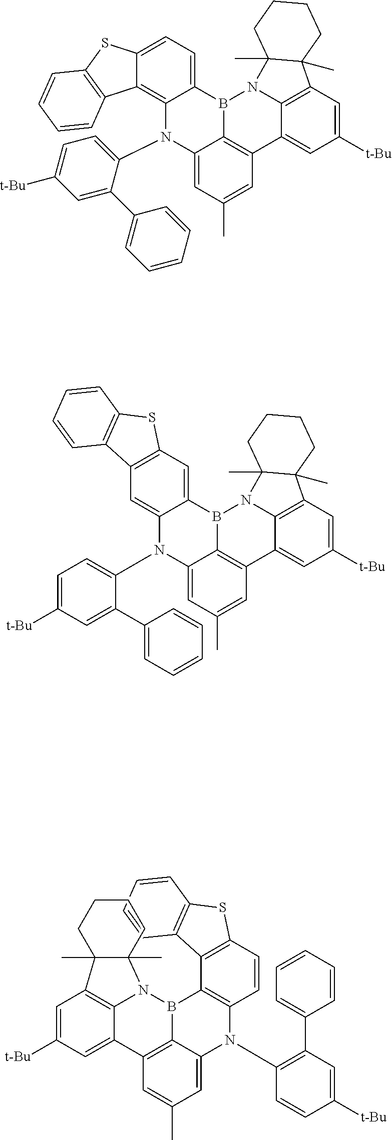 [SMILES: Cc1cc2c3c(c1)N(c1ccc(C(C)(C)C)cc1-c1ccccc1)c1c(ccc4sc5ccccc5c14)B3N1c3c-2cc(C(C)(C)C)cc3C2(C)CCCCC12C ; Cc1cc2c3c(c1)N(c1ccc(C(C)(C)C)cc1-c1ccccc1)c1cc4c(cc1B3N1c3c-2cc(C(C)(C)C)cc3C2(C)CCCCC12C)sc1ccccc14 ; Cc1cc2c3c(c1)N(c1ccc(C(C)(C)C)cc1-c1ccccc1)c1ccc4sc5ccccc5c4c1B3N1c3c-2cc(C(C)(C)C)cc3C2(C)CCCCC12C] 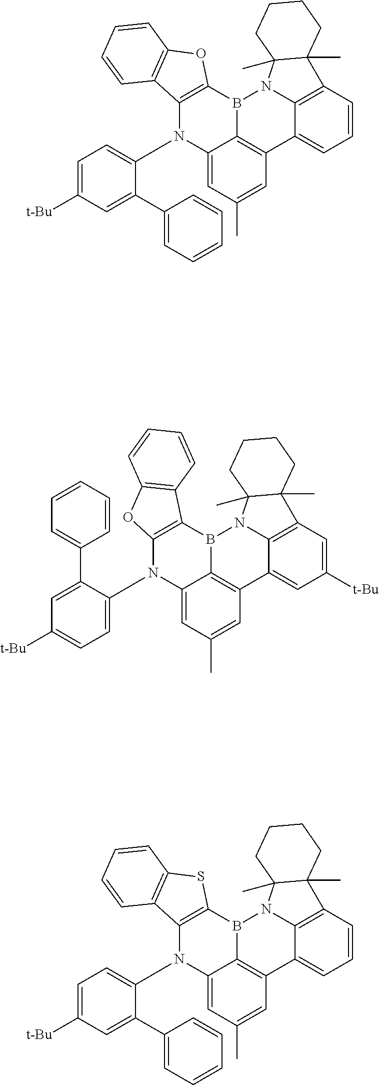 [SMILES: Cc1cc2c3c(c1)N(c1ccc(C(C)(C)C)cc1-c1ccccc1)c1c(oc4ccccc14)B3N1c3c-2cccc3C2(C)CCCCC12C ; Cc1cc2c3c(c1)N(c1ccc(C(C)(C)C)cc1-c1ccccc1)c1oc4ccccc4c1B3N1c3c-2cc(C(C)(C)C)cc3C2(C)CCCCC12C ; Cc1cc2c3c(c1)N(c1ccc(C(C)(C)C)cc1-c1ccccc1)c1c(sc4ccccc14)B3N1c3c-2cccc3C2(C)CCCCC12C] 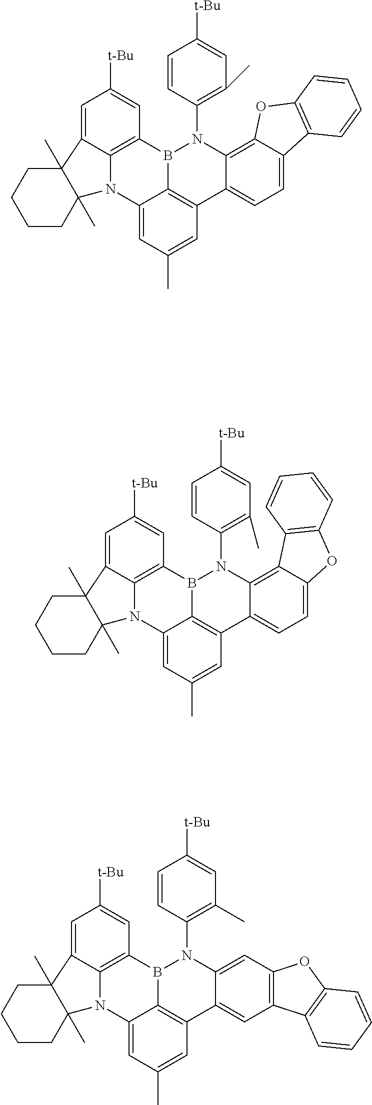 [SMILES: Cc1cc2c3c(c1)N1c4c(cc(C(C)(C)C)cc4C4(C)CCCCC14C)B3N(c1ccc(C(C)(C)C)cc1C)c1c-2ccc2c1oc1ccccc12 ; Cc1cc2c3c(c1)N1c4c(cc(C(C)(C)C)cc4C4(C)CCCCC14C)B3N(c1ccc(C(C)(C)C)cc1C)c1c-2ccc2oc3ccccc3c12 ; Cc1cc2c3c(c1)N1c4c(cc(C(C)(C)C)cc4C4(C)CCCCC14C)B3N(c1ccc(C(C)(C)C)cc1C)c1cc3oc4ccccc4c3cc1-2] 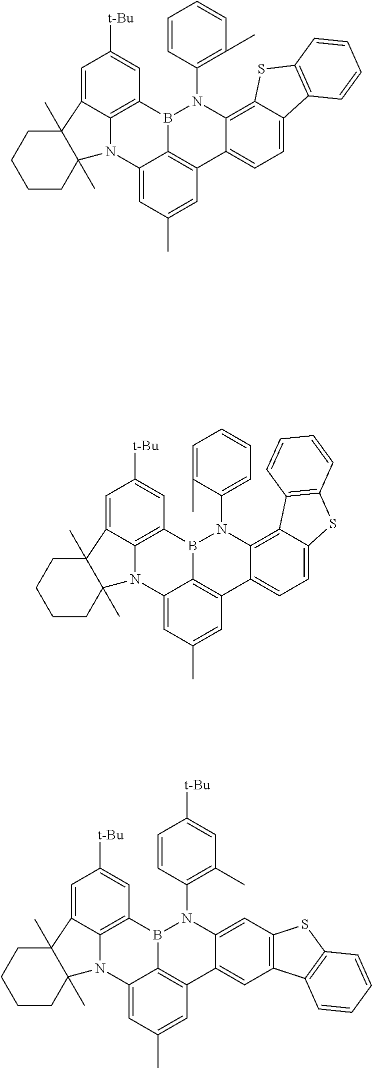 [SMILES: Cc1cc2c3c(c1)N1c4c(cc(C(C)(C)C)cc4C4(C)CCCCC14C)B3N(c1ccccc1C)c1c-2ccc2c1sc1ccccc12 ; Cc1cc2c3c(c1)N1c4c(cc(C(C)(C)C)cc4C4(C)CCCCC14C)B3N(c1ccccc1C)c1c-2ccc2sc3ccccc3c12 ; Cc1cc2c3c(c1)N1c4c(cc(C(C)(C)C)cc4C4(C)CCCCC14C)B3N(c1ccc(C(C)(C)C)cc1C)c1cc3sc4ccccc4c3cc1-2] 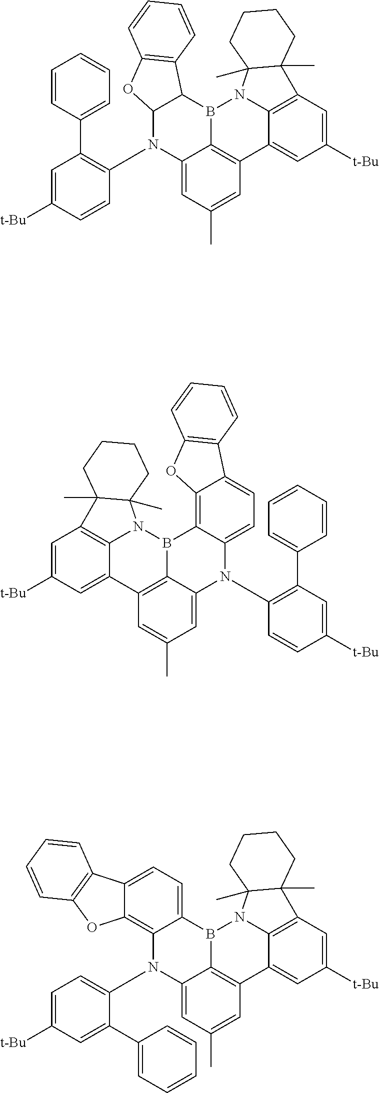 [SMILES: Cc1cc2c3c(c1)N(c1ccc(C(C)(C)C)cc1-c1ccccc1)C1Oc4ccccc4C1B3N1c3c-2cc(C(C)(C)C)cc3C2(C)CCCCC12C ; Cc1cc2c3c(c1)N(c1ccc(C(C)(C)C)cc1-c1ccccc1)c1ccc4c(oc5ccccc54)c1B3N1c3c-2cc(C(C)(C)C)cc3C2(C)CCCCC12C ; Cc1cc2c3c(c1)N(c1ccc(C(C)(C)C)cc1-c1ccccc1)c1c(ccc4c1oc1ccccc14)B3N1c3c-2cc(C(C)(C)C)cc3C2(C)CCCCC12C] 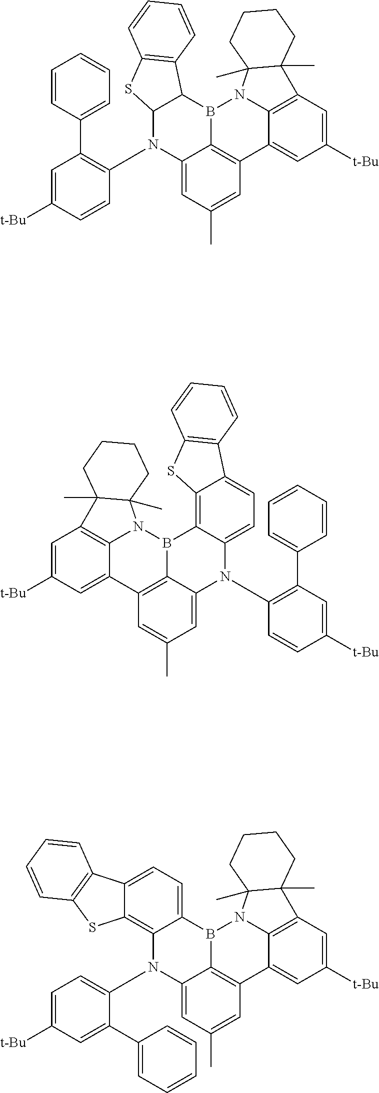 [SMILES: Cc1cc2c3c(c1)N(c1ccc(C(C)(C)C)cc1-c1ccccc1)C1Sc4ccccc4C1B3N1c3c-2cc(C(C)(C)C)cc3C2(C)CCCCC12C ; Cc1cc2c3c(c1)N(c1ccc(C(C)(C)C)cc1-c1ccccc1)c1ccc4c(sc5ccccc54)c1B3N1c3c-2cc(C(C)(C)C)cc3C2(C)CCCCC12C ; Cc1cc2c3c(c1)N(c1ccc(C(C)(C)C)cc1-c1ccccc1)c1c(ccc4c1sc1ccccc14)B3N1c3c-2cc(C(C)(C)C)cc3C2(C)CCCCC12C] 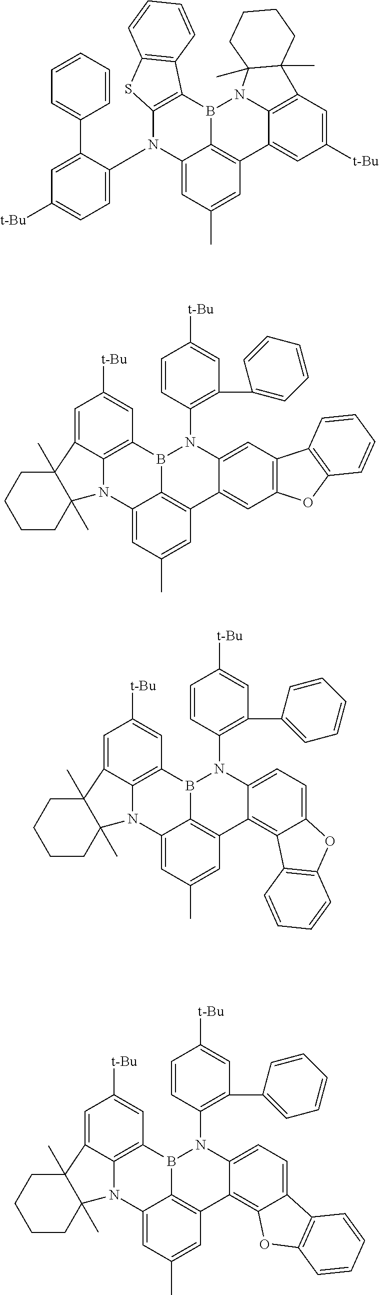 [SMILES: Cc1cc2c3c(c1)N(c1ccc(C(C)(C)C)cc1-c1ccccc1)c1sc4ccccc4c1B3N1c3c-2cc(C(C)(C)C)cc3C2(C)CCCCC12C ; Cc1cc2c3c(c1)N1c4c(cc(C(C)(C)C)cc4C4(C)CCCCC14C)B3N(c1ccc(C(C)(C)C)cc1-c1ccccc1)c1cc3c(cc1-2)oc1ccccc13 ; Cc1cc2c3c(c1)N1c4c(cc(C(C)(C)C)cc4C4(C)CCCCC14C)B3N(c1ccc(C(C)(C)C)cc1-c1ccccc1)c1ccc3oc4ccccc4c3c1-2 ; Cc1cc2c3c(c1)N1c4c(cc(C(C)(C)C)cc4C4(C)CCCCC14C)B3N(c1ccc(C(C)(C)C)cc1-c1ccccc1)c1ccc3c(oc4ccccc43)c1-2] 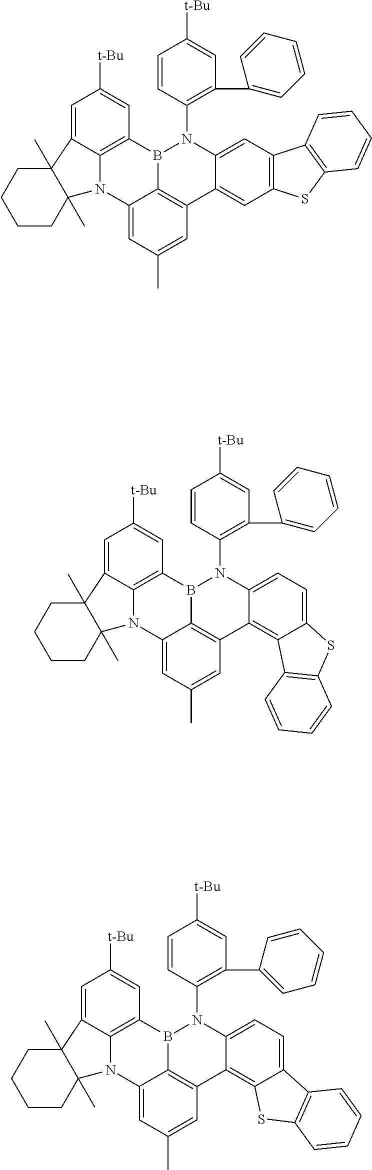 [SMILES: Cc1cc2c3c(c1)N1c4c(cc(C(C)(C)C)cc4C4(C)CCCCC14C)B3N(c1ccc(C(C)(C)C)cc1-c1ccccc1)c1cc3c(cc1-2)sc1ccccc13 ; Cc1cc2c3c(c1)N1c4c(cc(C(C)(C)C)cc4C4(C)CCCCC14C)B3N(c1ccc(C(C)(C)C)cc1-c1ccccc1)c1ccc3sc4ccccc4c3c1-2 ; Cc1cc2c3c(c1)N1c4c(cc(C(C)(C)C)cc4C4(C)CCCCC14C)B3N(c1ccc(C(C)(C)C)cc1-c1ccccc1)c1ccc3c(sc4ccccc43)c1-2] 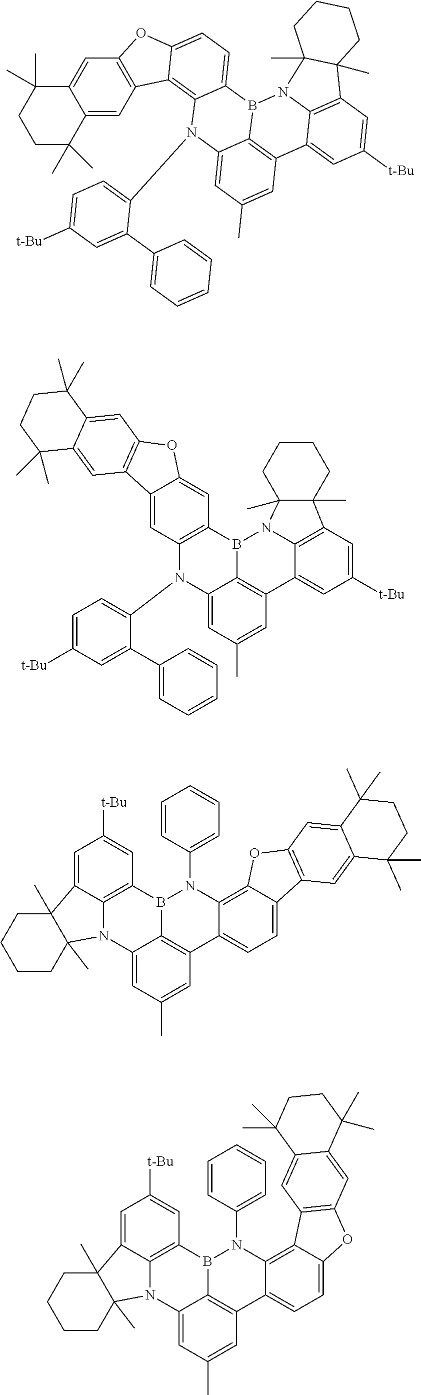 [SMILES: Cc1cc2c3c(c1)N(c1ccc(C(C)(C)C)cc1-c1ccccc1)c1c(ccc4oc5cc6c(cc5c14)C(C)(C)CCC6(C)C)B3N1c3c-2cc(C(C)(C)C)cc3C2(C)CCCCC12C ; Cc1cc2c3c(c1)N(c1ccc(C(C)(C)C)cc1-c1ccccc1)c1cc4c(cc1B3N1c3c-2cc(C(C)(C)C)cc3C2(C)CCCCC12C)oc1cc2c(cc14)C(C)(C)CCC2(C)C ; Cc1cc2c3c(c1)N1c4c(cc(C(C)(C)C)cc4C4(C)CCCCC14C)B3N(c1ccccc1)c1c-2ccc2c1oc1cc3c(cc12)C(C)(C)CCC3(C)C ; Cc1cc2c3c(c1)N1c4c(cc(C(C)(C)C)cc4C4(C)CCCCC14C)B3N(c1ccccc1)c1c-2ccc2oc3cc4c(cc3c12)C(C)(C)CCC4(C)C] 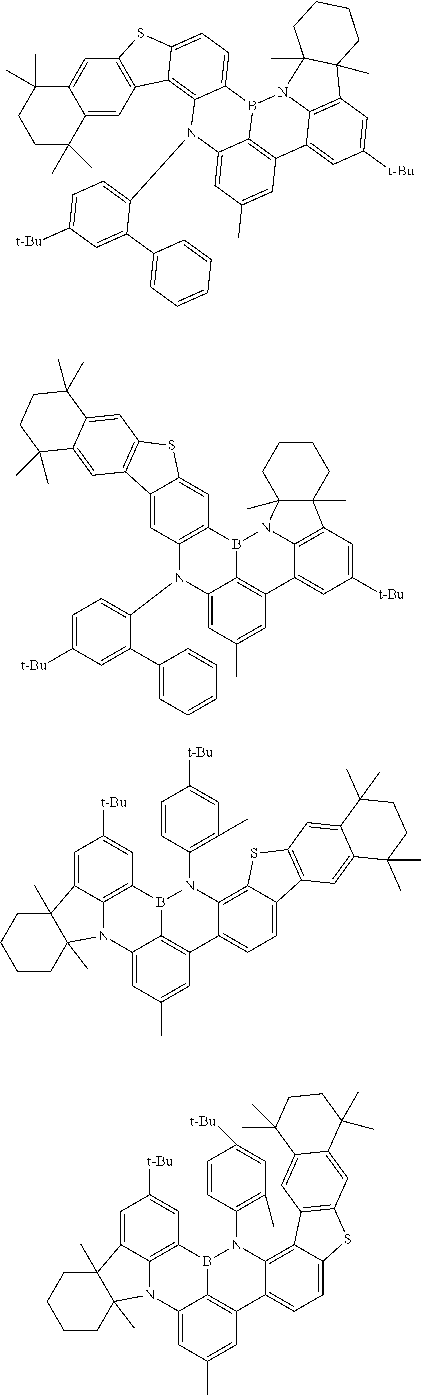 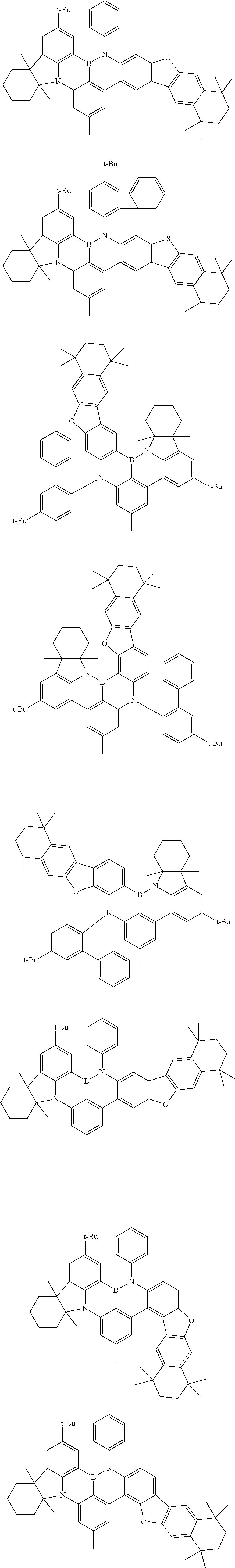 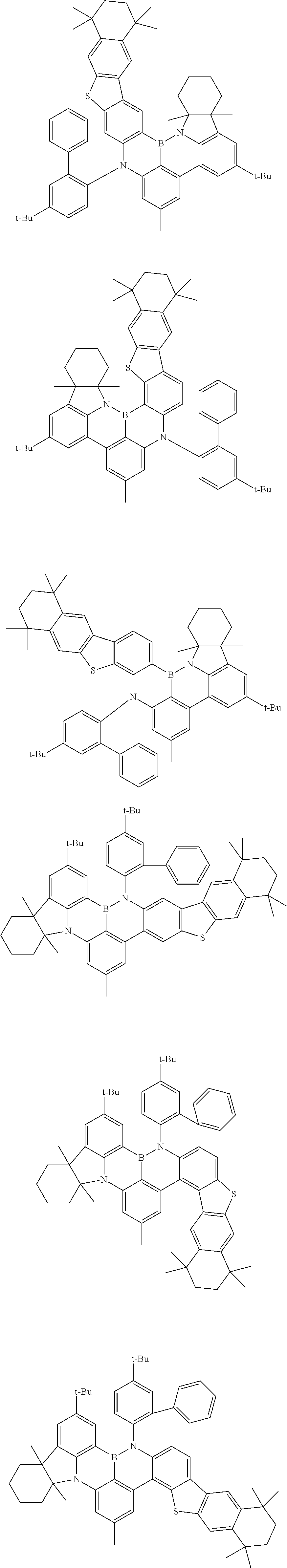 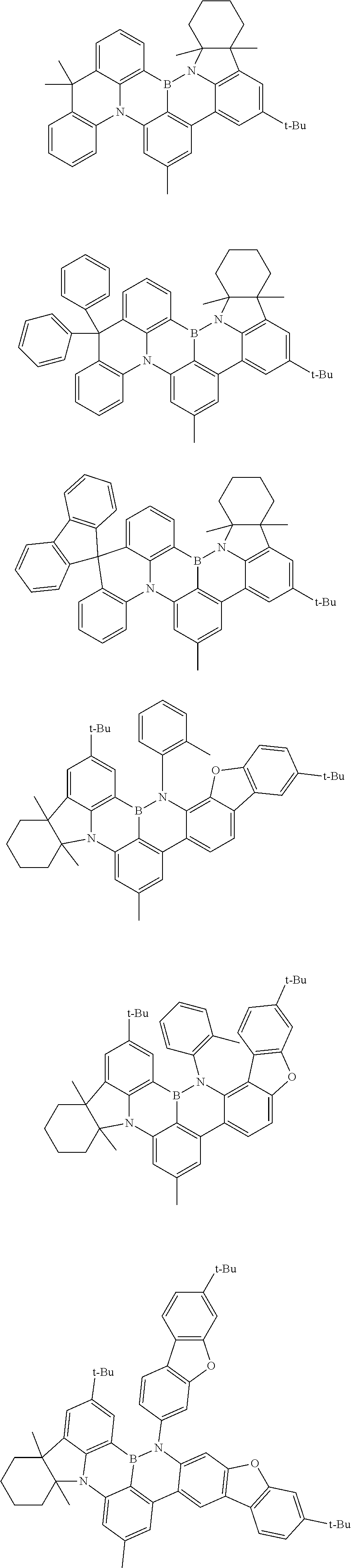 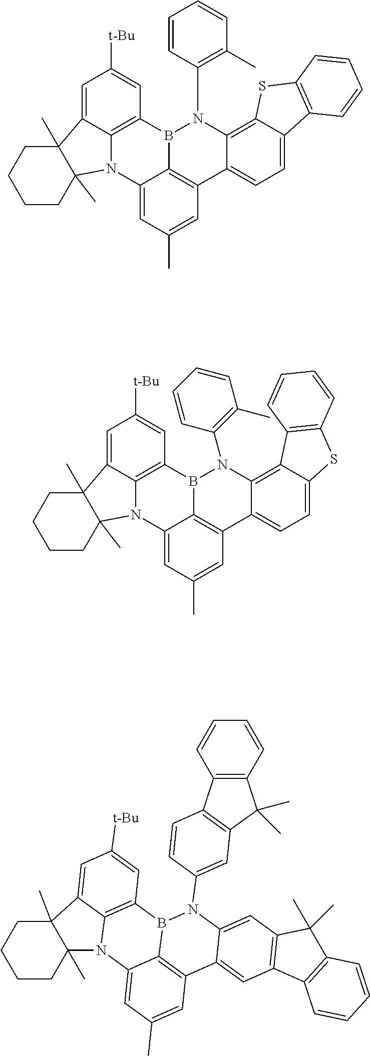 [SMILES: Cc1cc2c3c(c1)N1c4c(cc(C(C)(C)C)cc4C4(C)CCCCC14C)B3N(c1ccccc1C)c1c-2ccc2c1sc1ccccc12 ; Cc1cc2c3c(c1)N1c4c(cc(C(C)(C)C)cc4C4(C)CCCCC14C)B3N(c1ccccc1C)c1c-2ccc2sc3ccccc3c12 ; Cc1cc2c3c(c1)N1c4c(cc(C(C)(C)C)cc4C4(C)CCCCC14C)B3N(c1ccc3c(c1)C(C)(C)c1ccccc1-3)c1cc3c(cc1-2)-c1ccccc1C3(C)C] 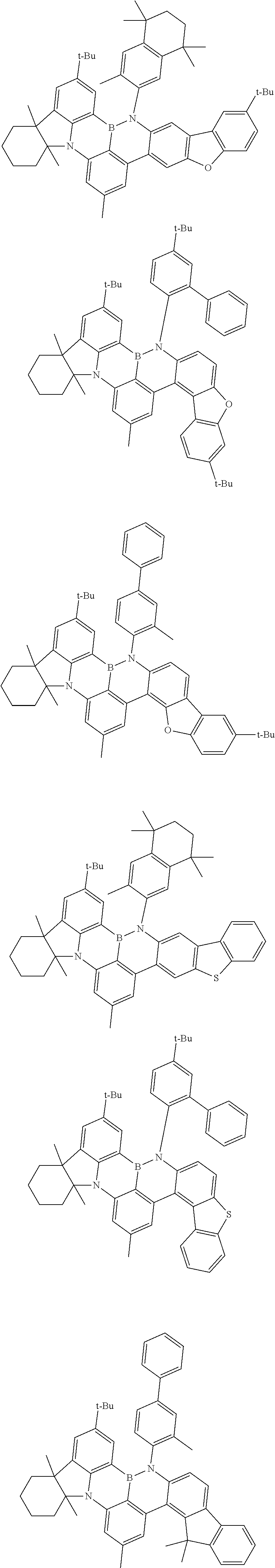 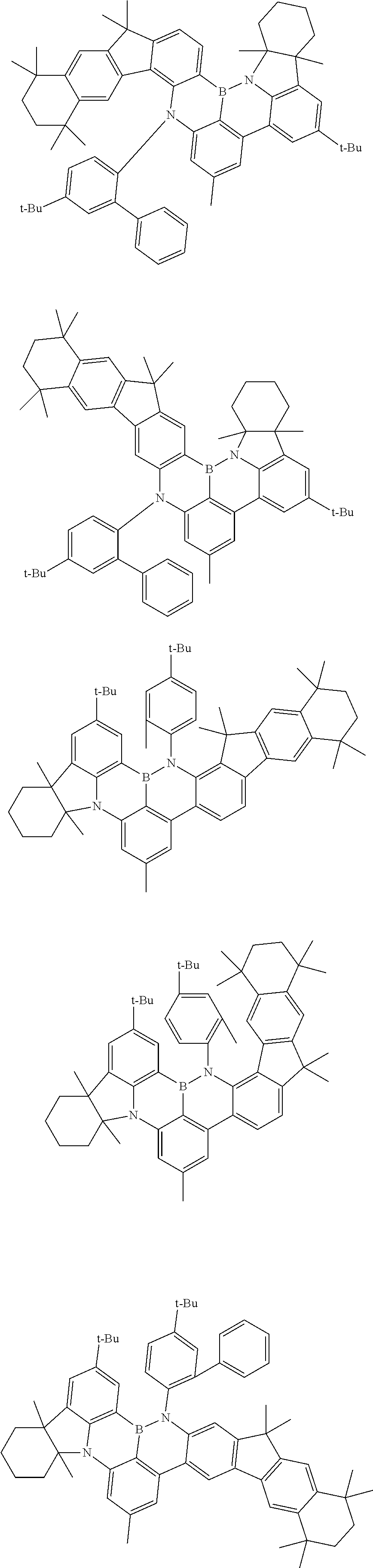 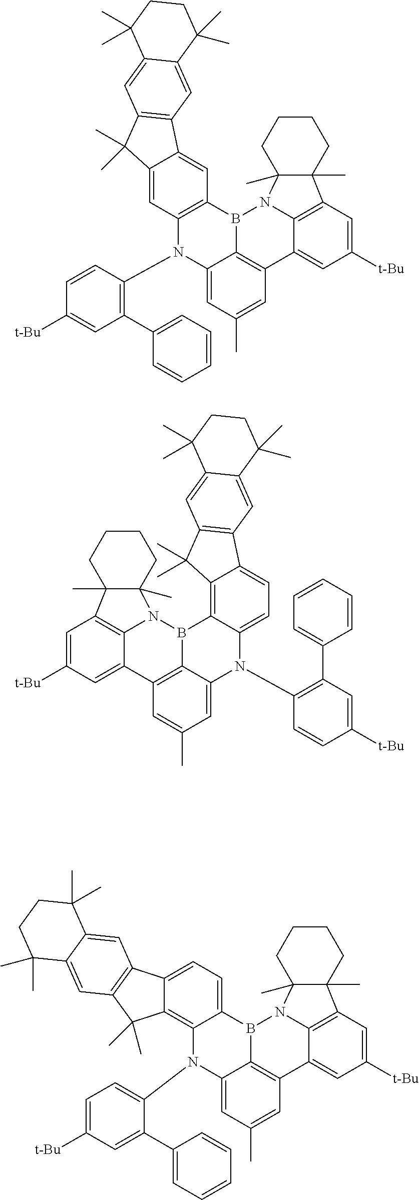 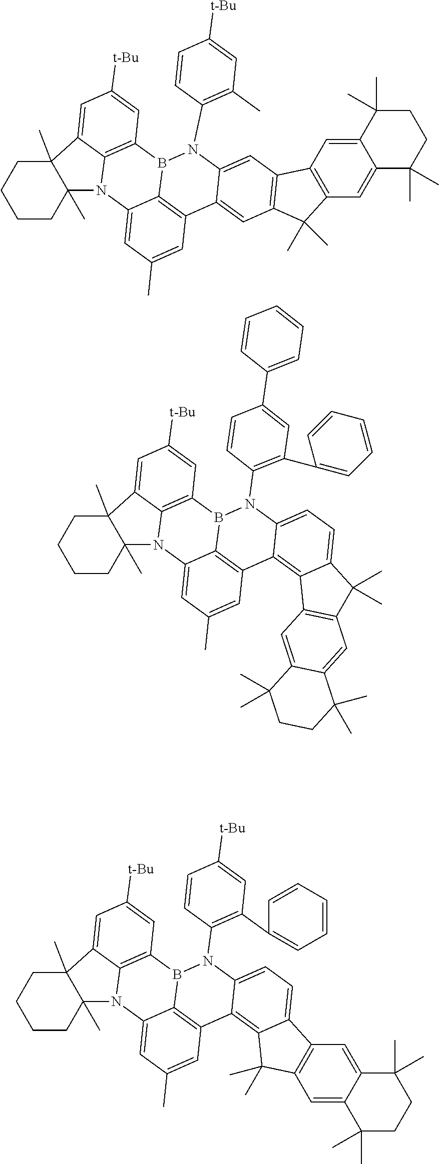 [SMILES: Cc1cc2c3c(c1)N1c4c(cc(C(C)(C)C)cc4C4(C)CCCCC14C)B3N(c1ccc(C(C)(C)C)cc1C)c1cc3c(cc1-2)C(C)(C)c1cc2c(cc1-3)C(C)(C)CCC2(C)C ; Cc1cc2c3c(c1)N1c4c(cc(C(C)(C)C)cc4C4(C)CCCCC14C)B3N(c1ccc(-c3ccccc3)cc1-c1ccccc1)c1ccc3c(c1-2)-c1cc2c(cc1C3(C)C)C(C)(C)CCC2(C)C ; Cc1cc2c3c(c1)N1c4c(cc(C(C)(C)C)cc4C4(C)CCCCC14C)B3N(c1ccc(C(C)(C)C)cc1-c1ccccc1)c1ccc3c(c1-2)C(C)(C)c1cc2c(cc1-3)C(C)(C)CCC2(C)C] 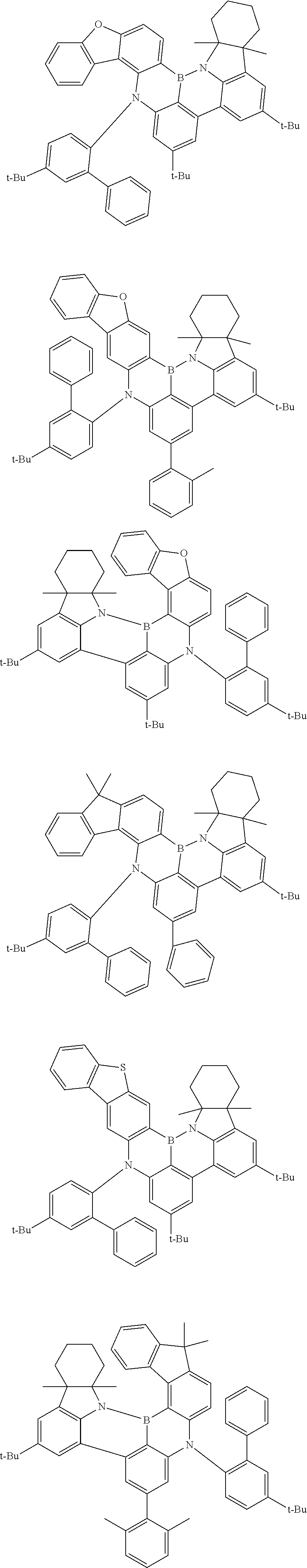 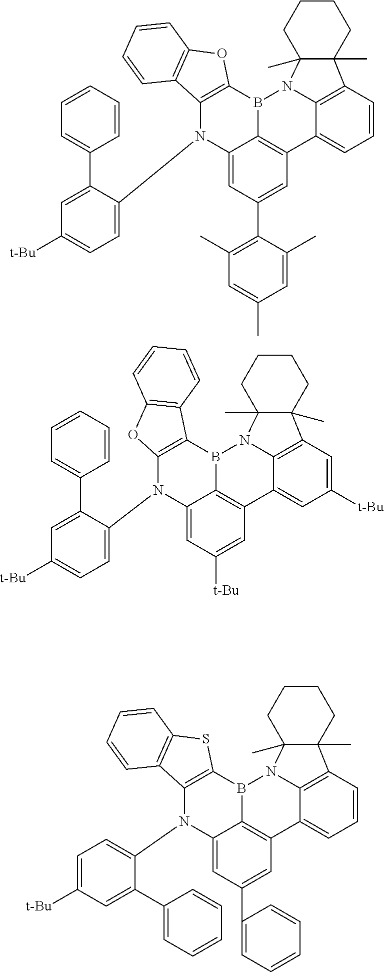 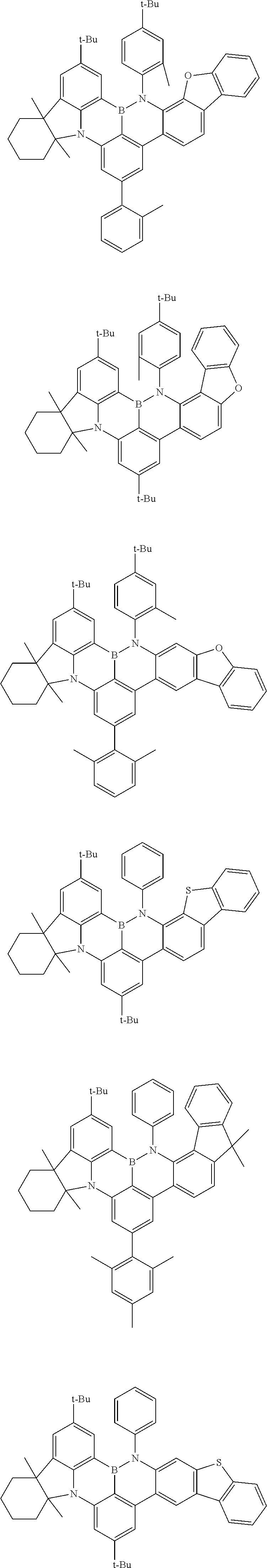 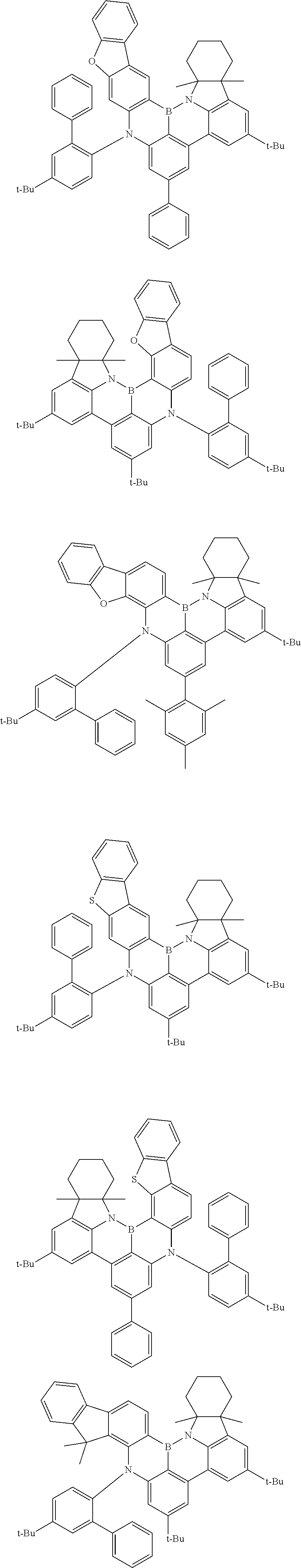 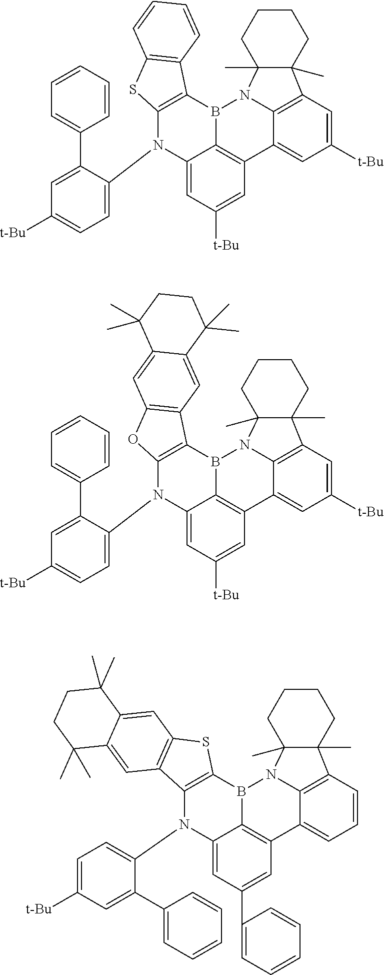 [SMILES: CC(C)(C)c1ccc(N2c3cc(C(C)(C)C)cc4c3B(c3c2sc2ccccc32)N2c3c-4cc(C(C)(C)C)cc3C3(C)CCCCC23C)c(-c2ccccc2)c1 ; CC(C)(C)c1ccc(N2c3cc(C(C)(C)C)cc4c3B(c3c2oc2cc5c(cc32)C(C)(C)CCC5(C)C)N2c3c-4cc(C(C)(C)C)cc3C3(C)CCCCC23C)c(-c2ccccc2)c1 ; CC(C)(C)c1ccc(N2c3cc(-c4ccccc4)cc4c3B(c3sc5cc6c(cc5c32)C(C)(C)CCC6(C)C)N2c3c-4cccc3C3(C)CCCCC23C)c(-c2ccccc2)c1] 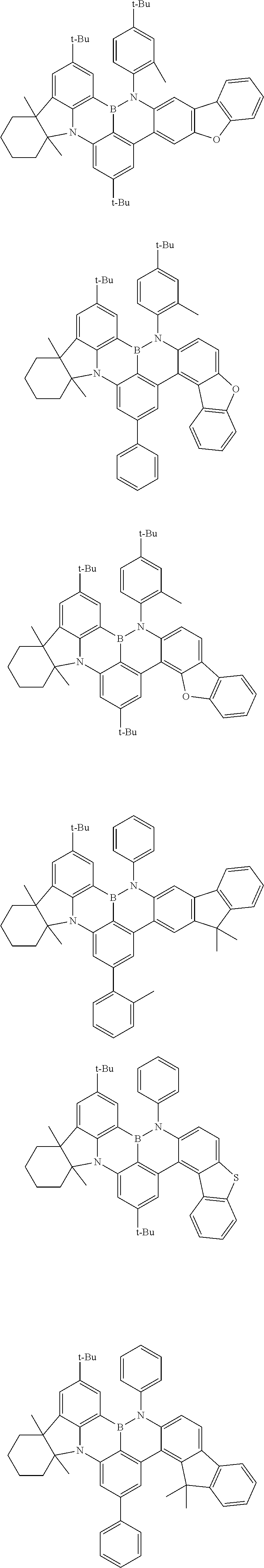 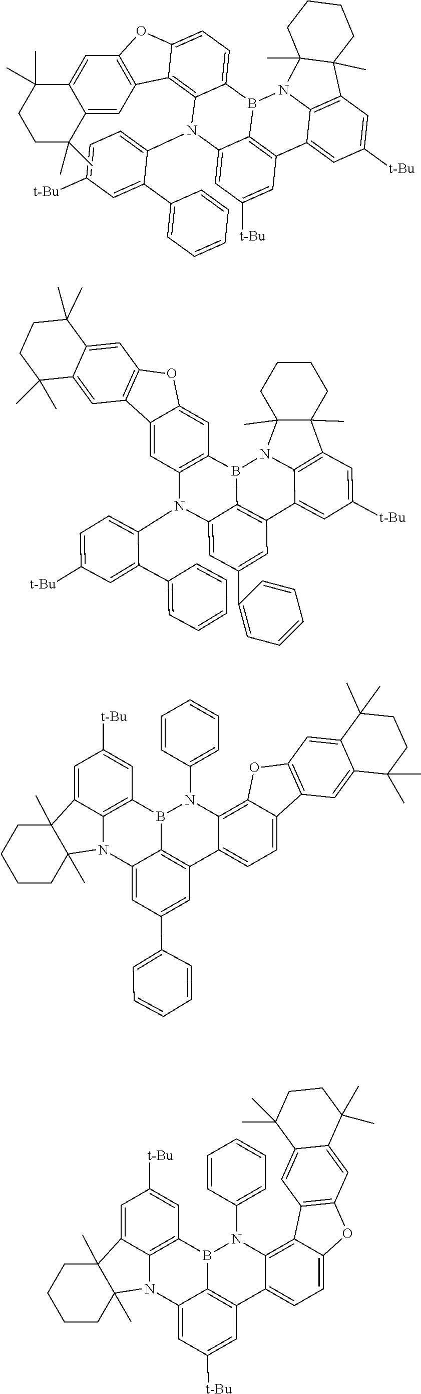 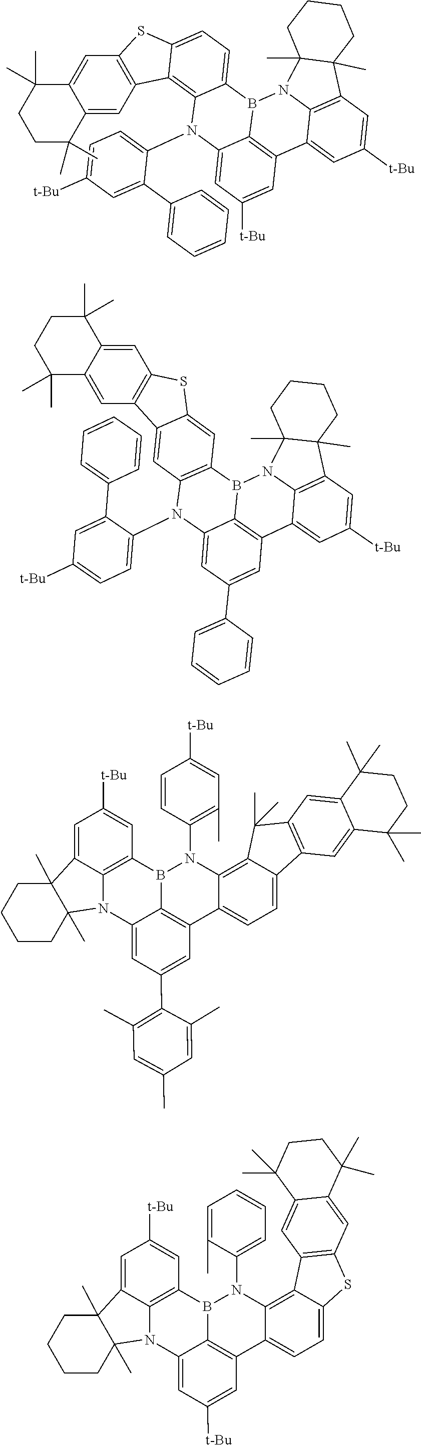 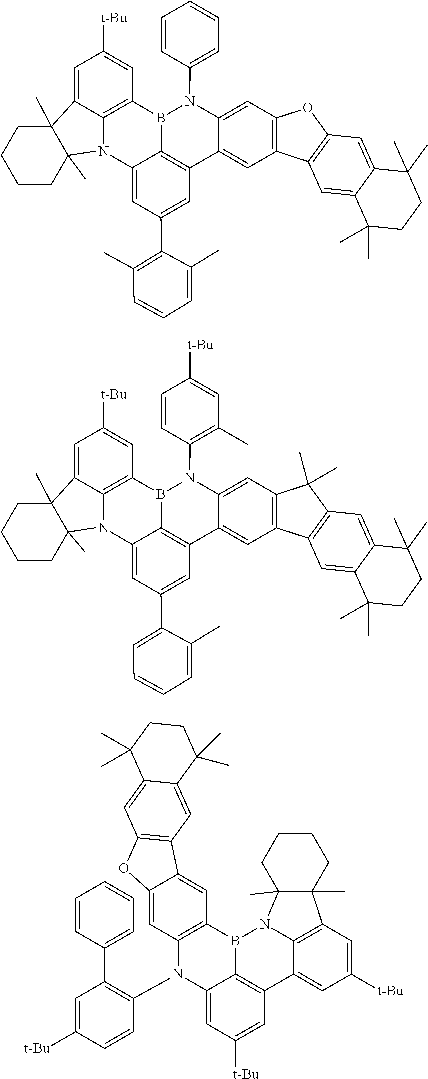 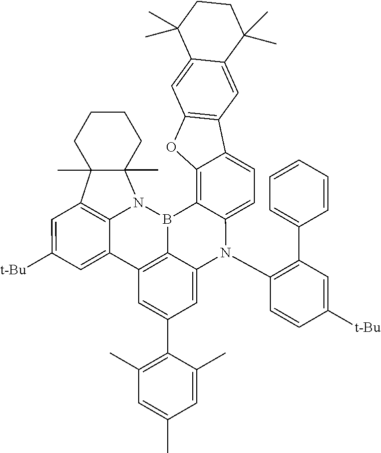 [SMILES: Cc1cc(C)c(-c2cc3c4c(c2)N(c2ccc(C(C)(C)C)cc2-c2ccccc2)c2ccc5c(oc6cc7c(cc65)C(C)(C)CCC7(C)C)c2B4N2c4c-3cc(C(C)(C)C)cc4C3(C)CCCCC23C)c(C)c1] 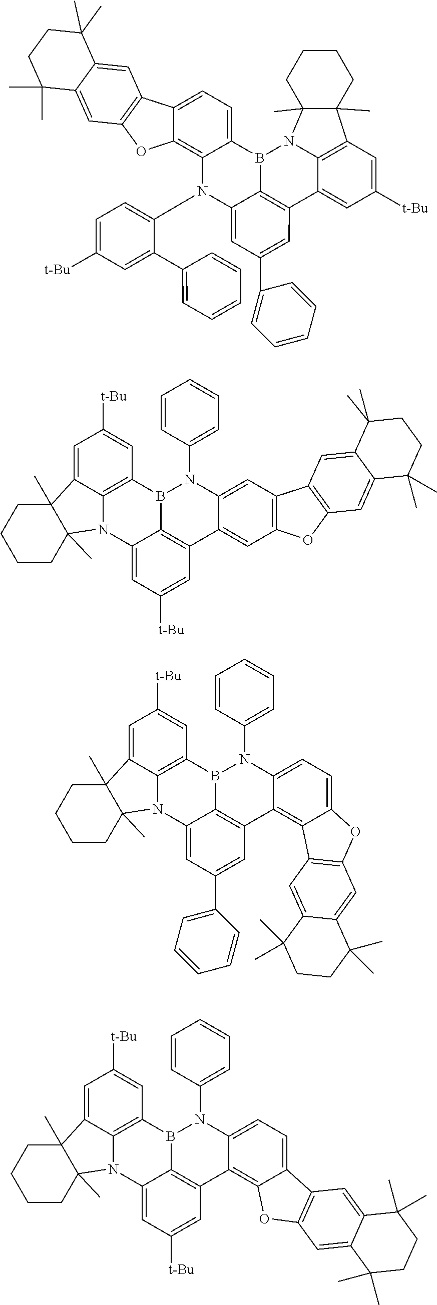 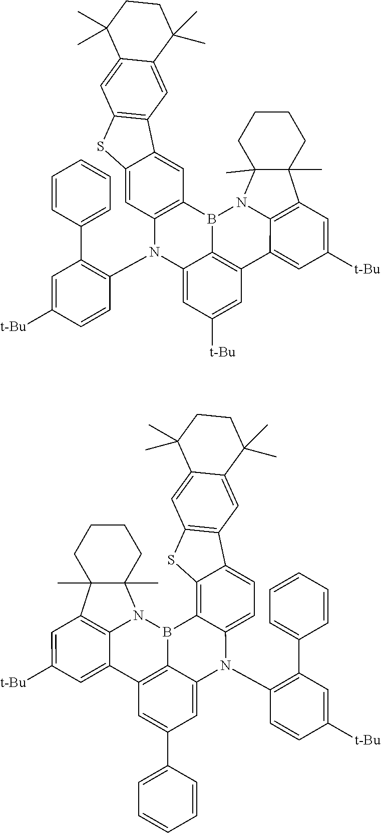 [SMILES: CC(C)(C)c1ccc(N2c3cc4sc5cc6c(cc5c4cc3B3c4c(cc(C(C)(C)C)cc42)-c2cc(C(C)(C)C)cc4c2N3C2(C)CCCCC42C)C(C)(C)CCC6(C)C)c(-c2ccccc2)c1 ; CC(C)(C)c1ccc(N2c3cc(-c4ccccc4)cc4c3B(c3c2ccc2c3sc3cc5c(cc32)C(C)(C)CCC5(C)C)N2c3c-4cc(C(C)(C)C)cc3C3(C)CCCCC23C)c(-c2ccccc2)c1] 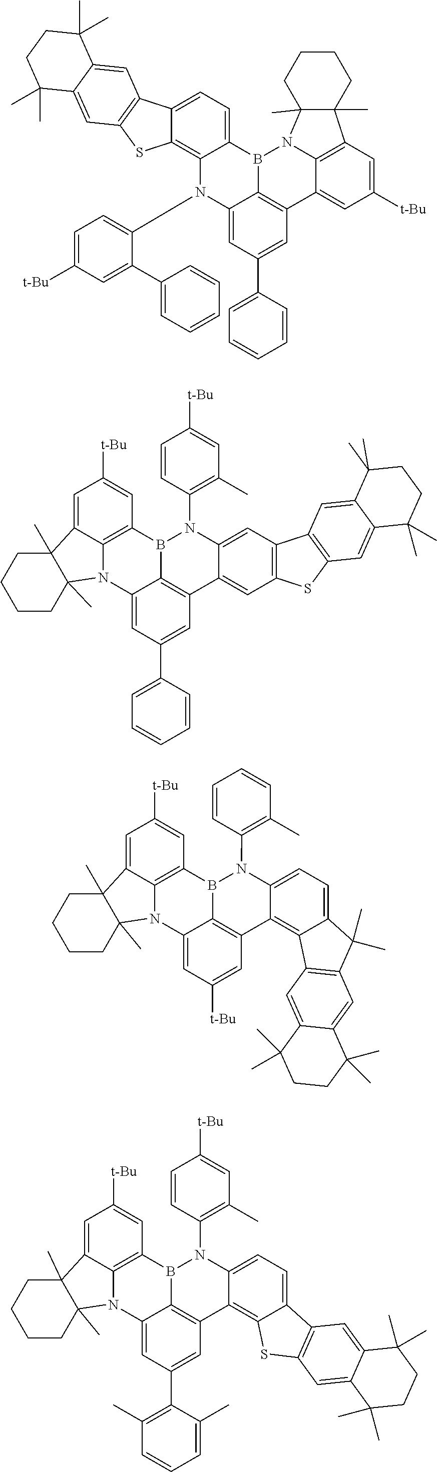 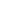 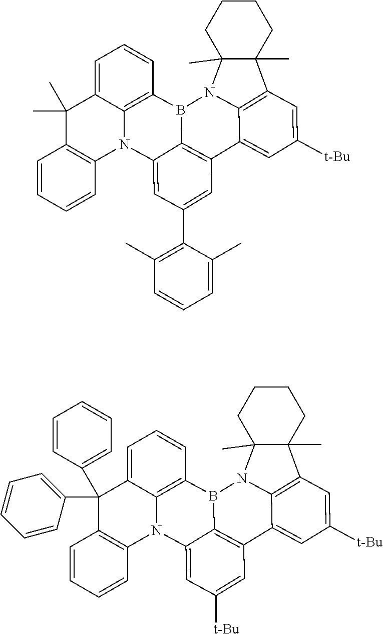 [SMILES: Cc1cccc(C)c1-c1cc2c3c(c1)N1c4ccccc4C(C)(C)c4cccc(c41)B3N1c3c-2cc(C(C)(C)C)cc3C2(C)CCCCC12C ; CC(C)(C)c1cc2c3c(c1)N1c4ccccc4C(c4ccccc4)(c4ccccc4)c4cccc(c41)B3N1c3c-2cc(C(C)(C)C)cc3C2(C)CCCCC12C] 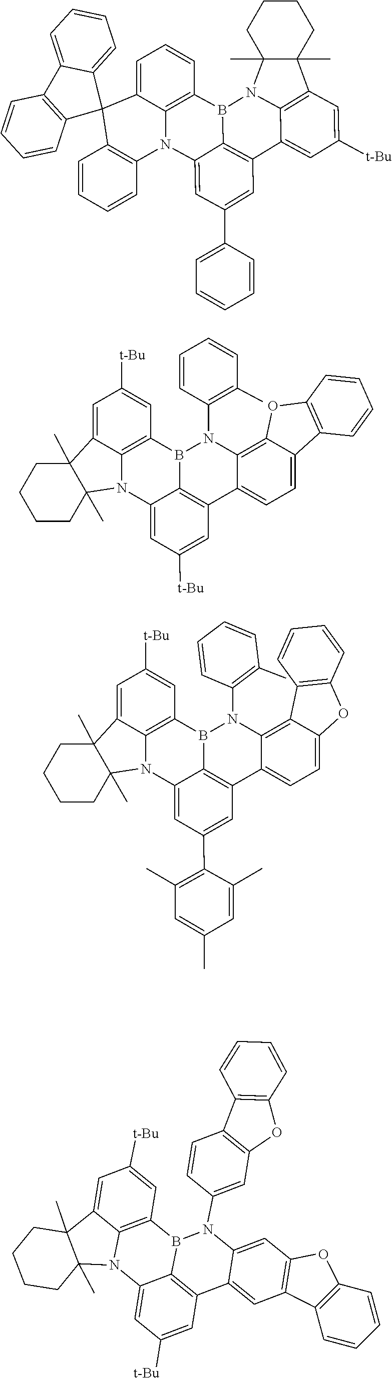 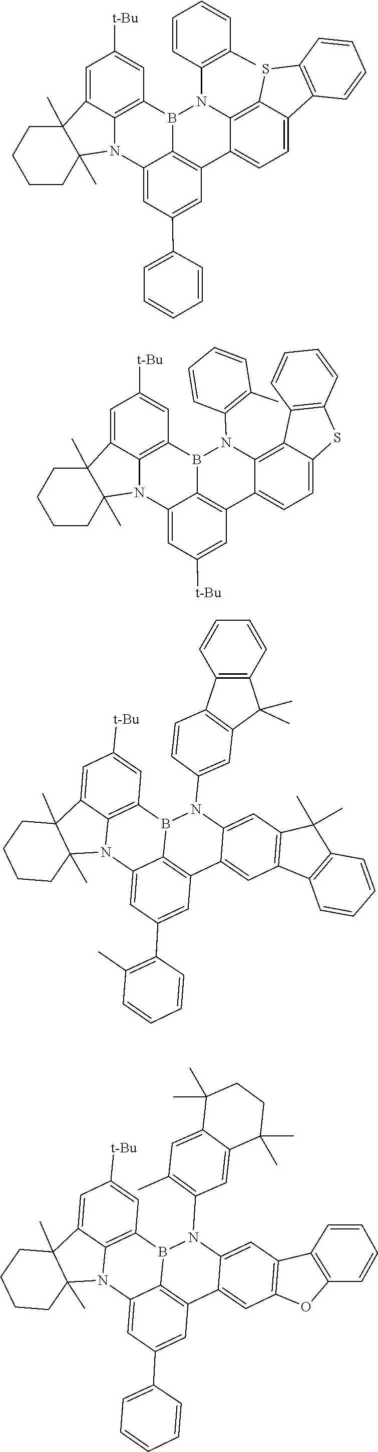 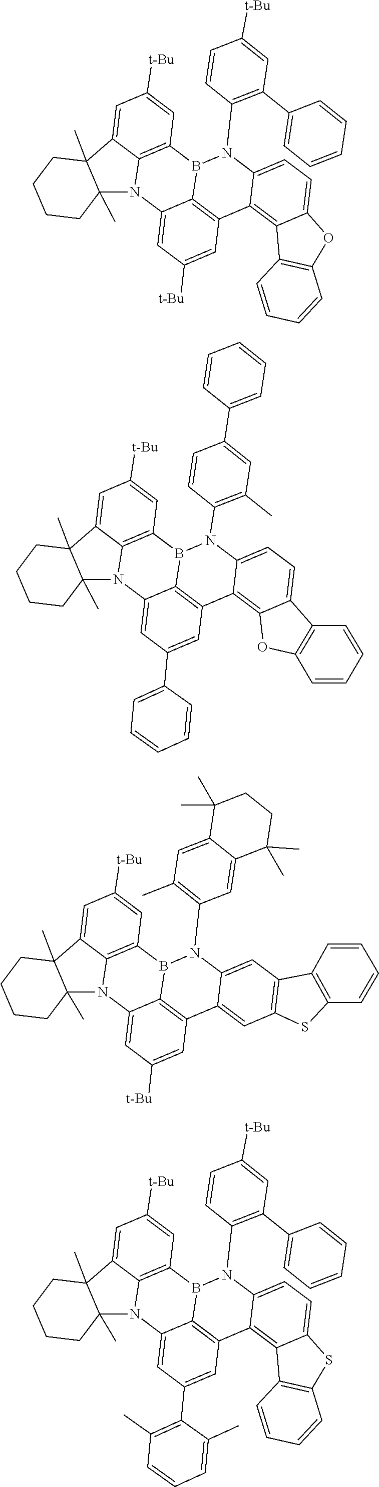 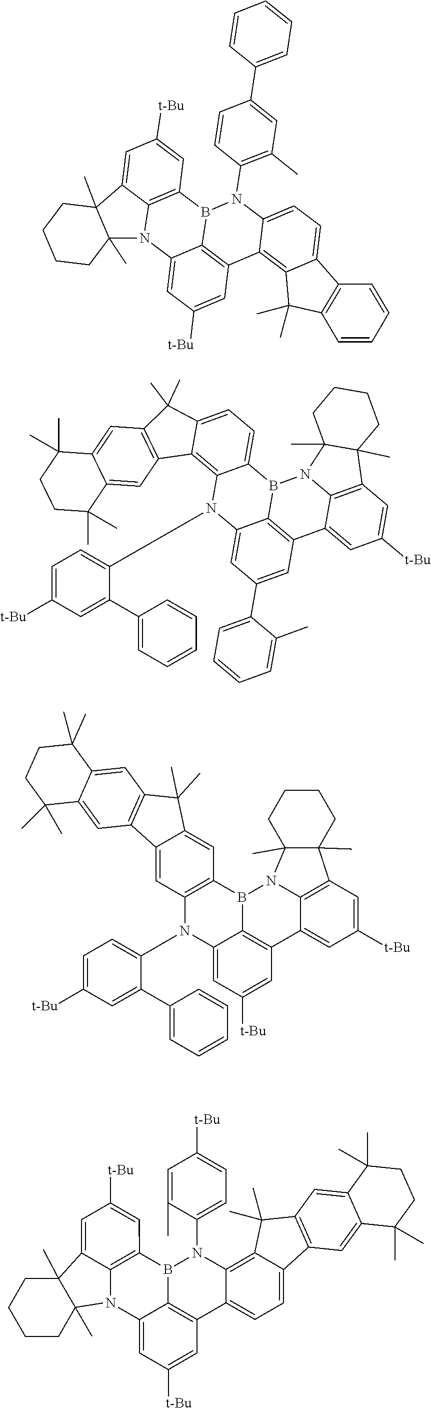 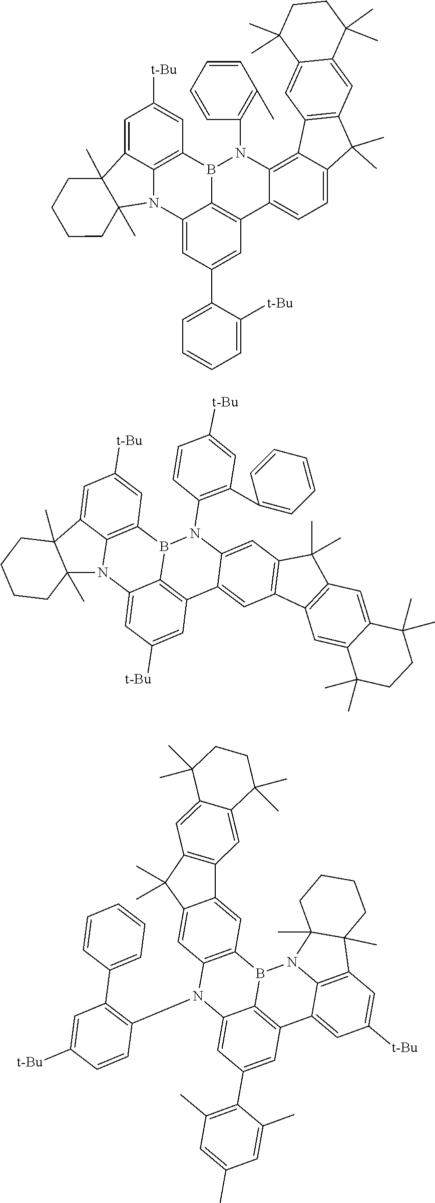 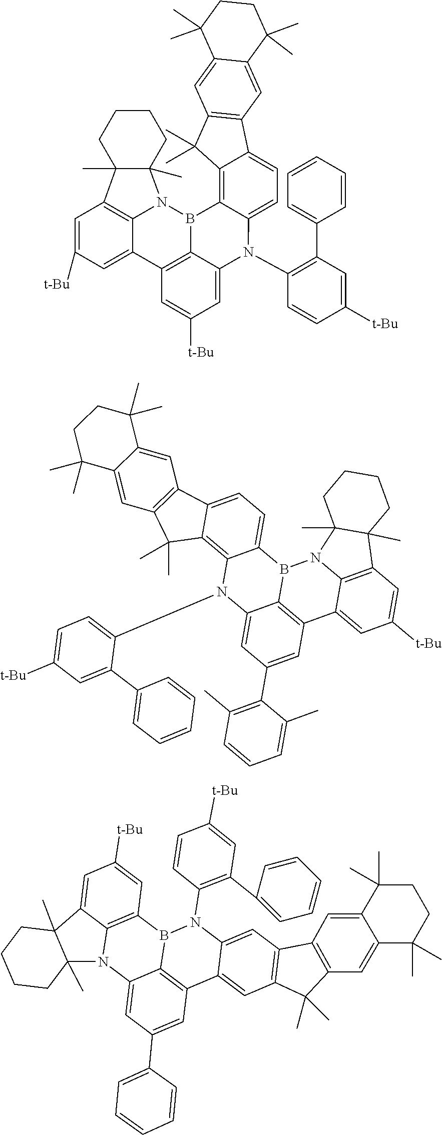 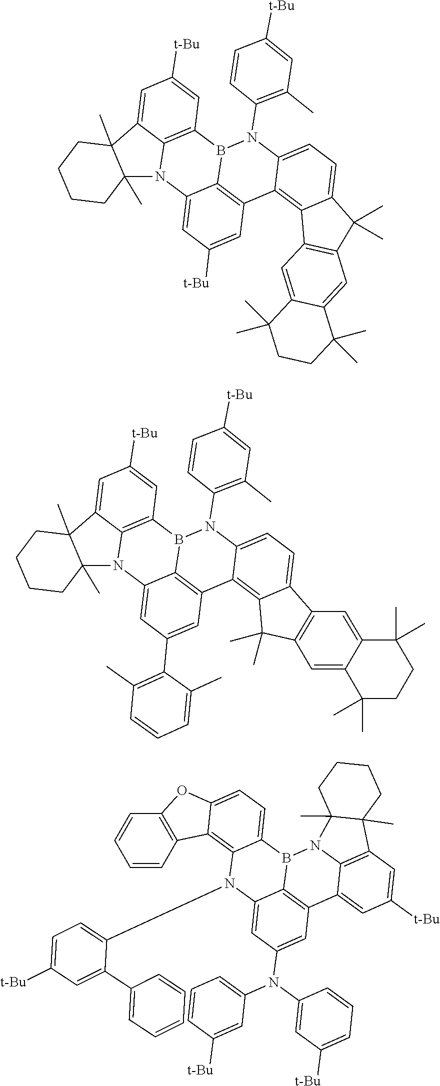 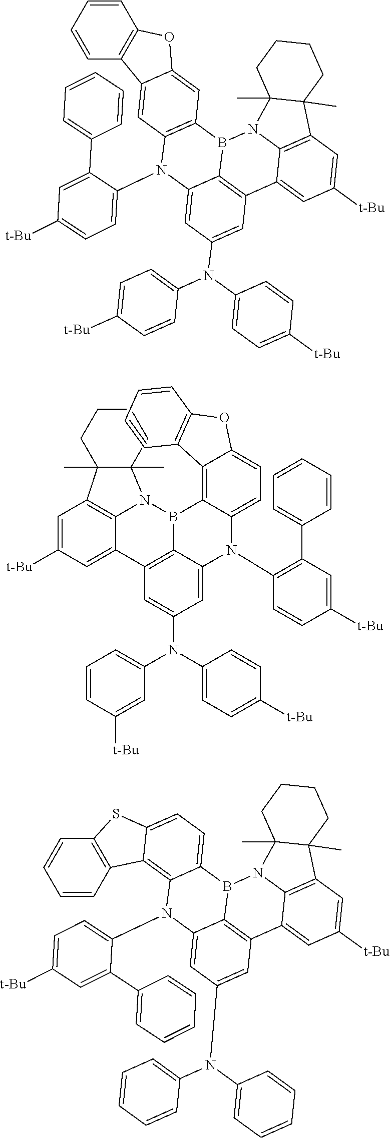 [SMILES: CC(C)(C)c1ccc(N(c2ccc(C(C)(C)C)cc2)c2cc3c4c(c2)N(c2ccc(C(C)(C)C)cc2-c2ccccc2)c2cc5c(cc2B4N2c4c-3cc(C(C)(C)C)cc4C3(C)CCCCC23C)oc2ccccc25)cc1 ; CC(C)(C)c1ccc(N(c2cccc(C(C)(C)C)c2)c2cc3c4c(c2)N(c2ccc(C(C)(C)C)cc2-c2ccccc2)c2ccc5oc6ccccc6c5c2B4N2c4c-3cc(C(C)(C)C)cc4C3(C)CCCCC23C)cc1 ; CC(C)(C)c1ccc(N2c3cc(N(c4ccccc4)c4ccccc4)cc4c3B(c3ccc5sc6ccccc6c5c32)N2c3c-4cc(C(C)(C)C)cc3C3(C)CCCCC23C)c(-c2ccccc2)c1] 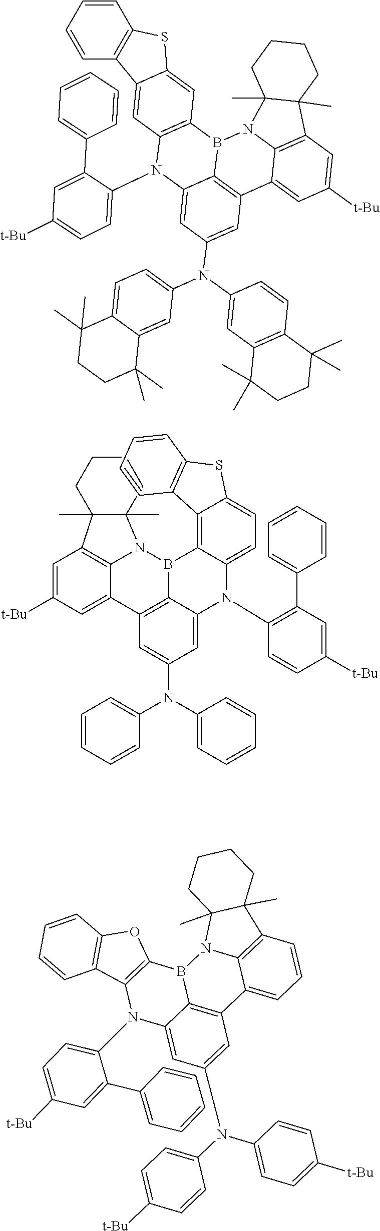 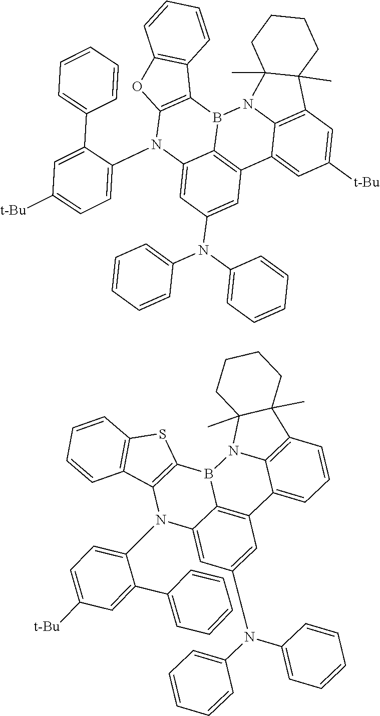 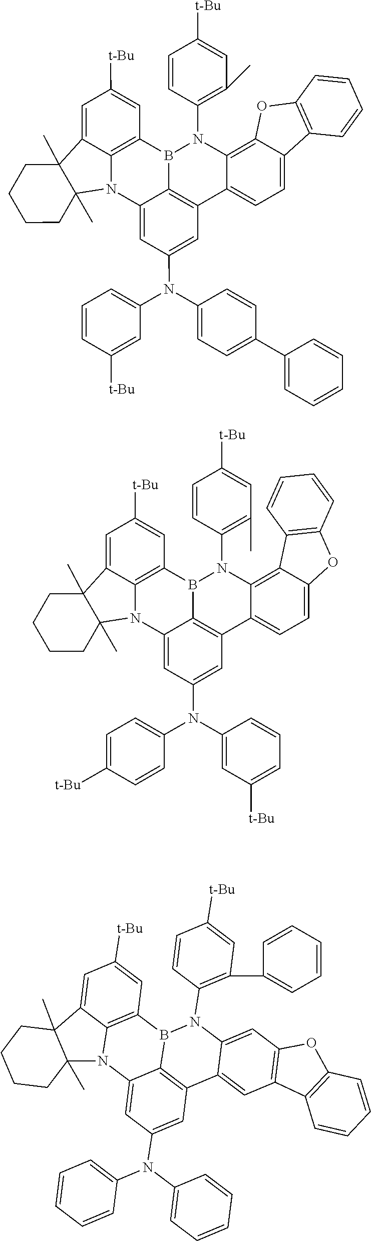 [SMILES: Cc1cc(C(C)(C)C)ccc1N1B2c3cc(C(C)(C)C)cc4c3N(c3cc(N(c5ccc(-c6ccccc6)cc5)c5cccc(C(C)(C)C)c5)cc(c32)-c2ccc3c(oc5ccccc53)c21)C1(C)CCCCC41C ; Cc1cc(C(C)(C)C)ccc1N1B2c3cc(C(C)(C)C)cc4c3N(c3cc(N(c5ccc(C(C)(C)C)cc5)c5cccc(C(C)(C)C)c5)cc(c32)-c2ccc3oc5ccccc5c3c21)C1(C)CCCCC41C ; CC(C)(C)c1ccc(N2B3c4cc(C(C)(C)C)cc5c4N(c4cc(N(c6ccccc6)c6ccccc6)cc(c43)-c3cc4c(cc32)oc2ccccc24)C2(C)CCCCC52C)c(-c2ccccc2)c1] 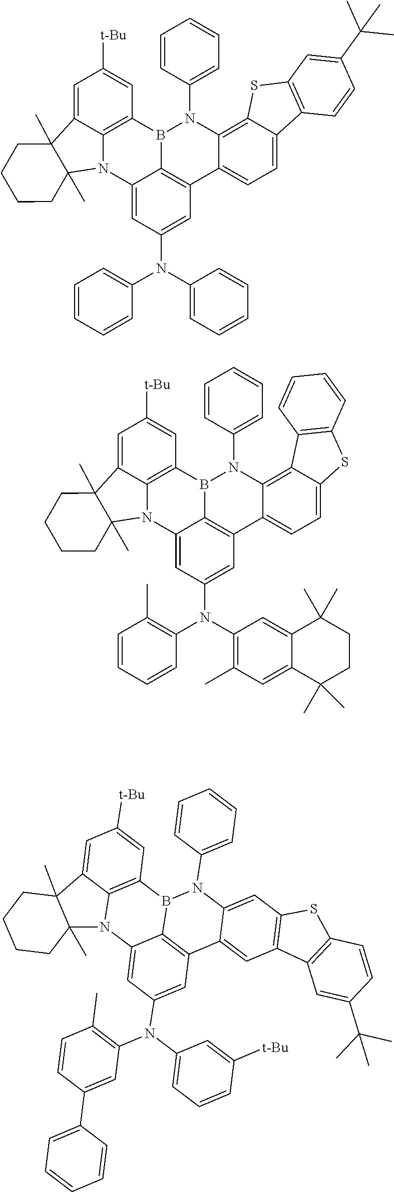 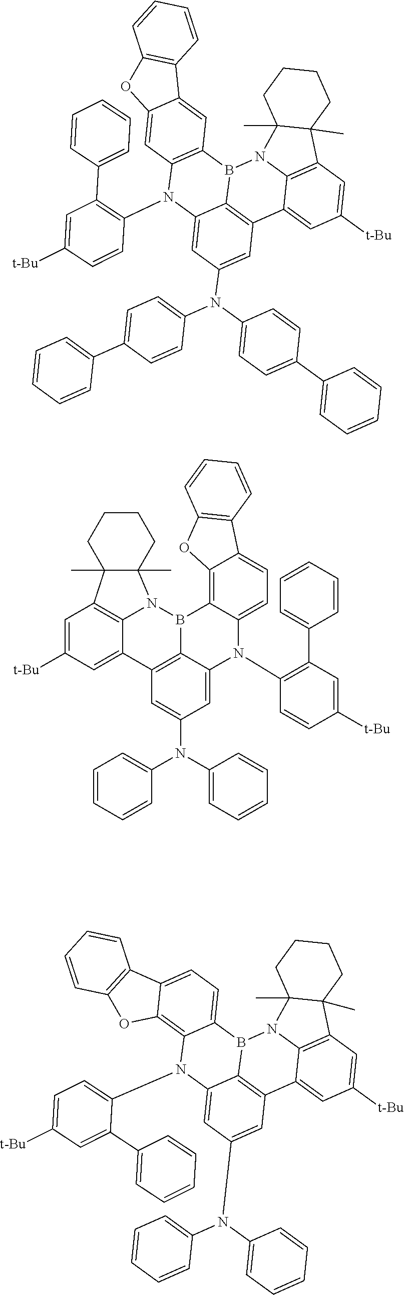 [SMILES: CC(C)(C)c1ccc(N2c3cc4oc5ccccc5c4cc3B3c4c(cc(N(c5ccc(-c6ccccc6)cc5)c5ccc(-c6ccccc6)cc5)cc42)-c2cc(C(C)(C)C)cc4c2N3C2(C)CCCCC42C)c(-c2ccccc2)c1 ; CC(C)(C)c1ccc(N2c3cc(N(c4ccccc4)c4ccccc4)cc4c3B(c3c2ccc2c3oc3ccccc32)N2c3c-4cc(C(C)(C)C)cc3C3(C)CCCCC23C)c(-c2ccccc2)c1 ; CC(C)(C)c1ccc(N2c3cc(N(c4ccccc4)c4ccccc4)cc4c3B(c3ccc5c(oc6ccccc65)c32)N2c3c-4cc(C(C)(C)C)cc3C3(C)CCCCC23C)c(-c2ccccc2)c1] 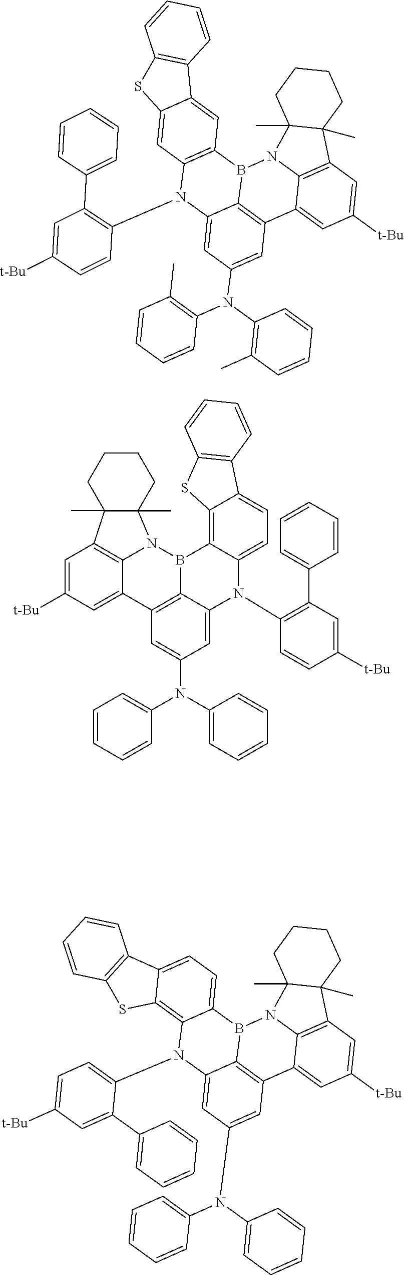 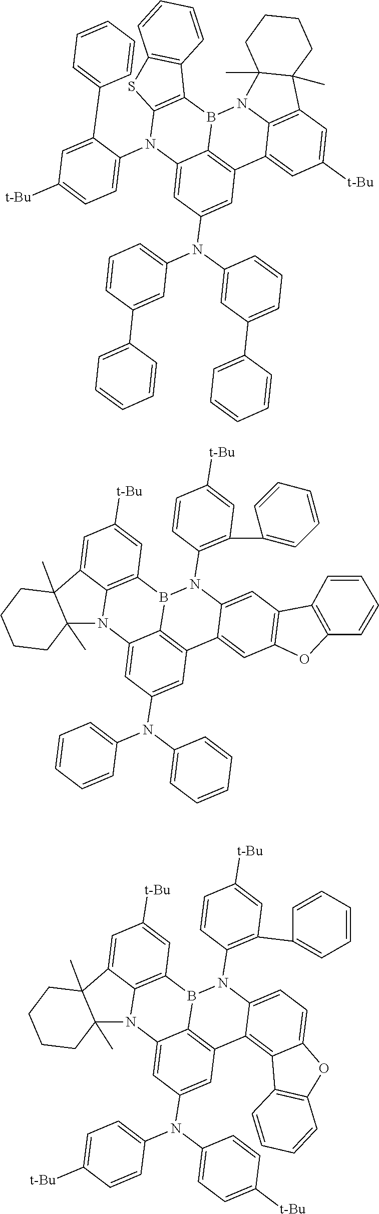 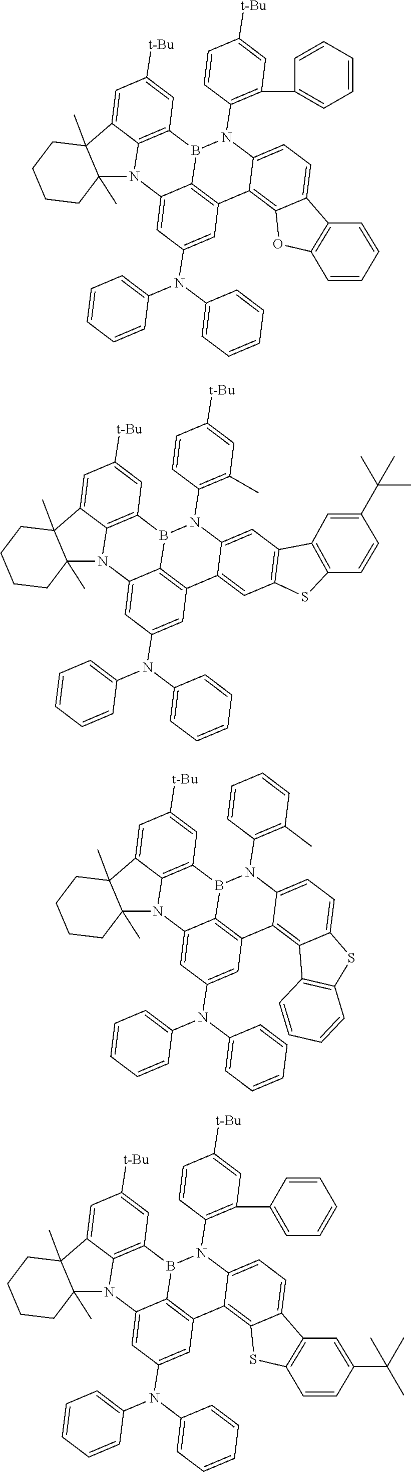 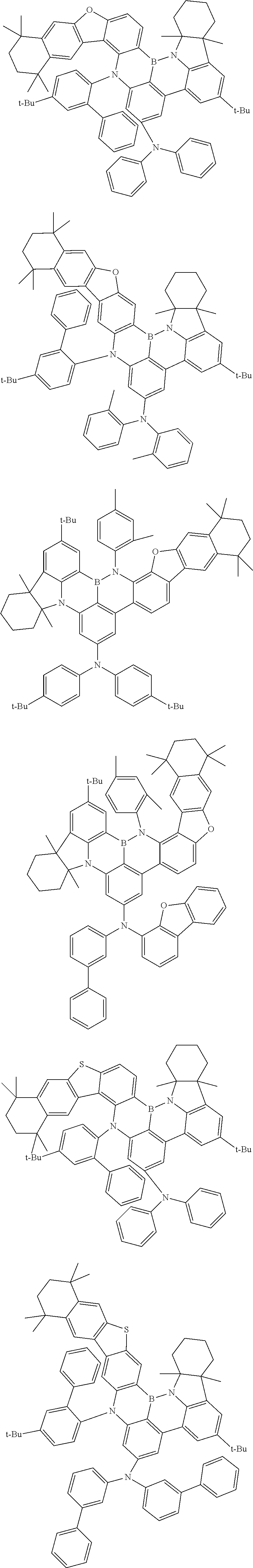 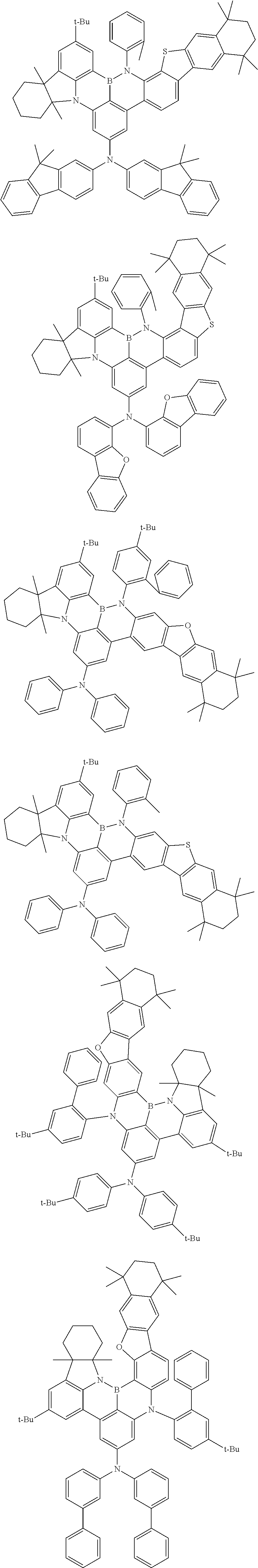 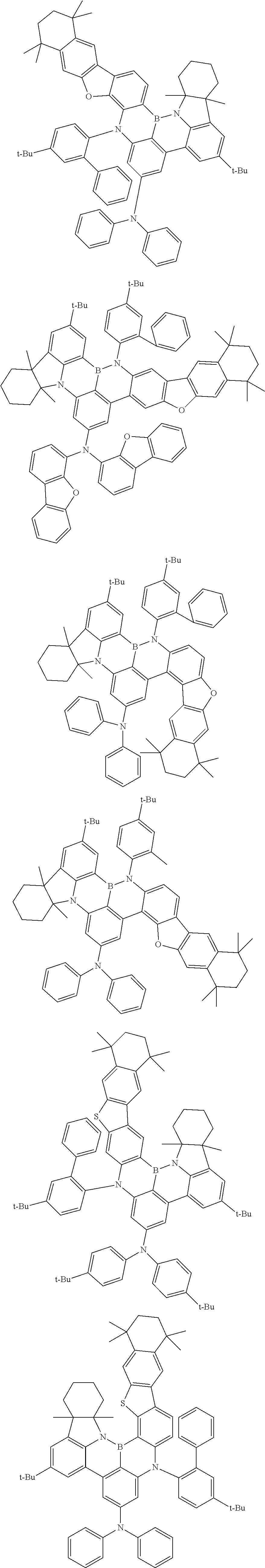 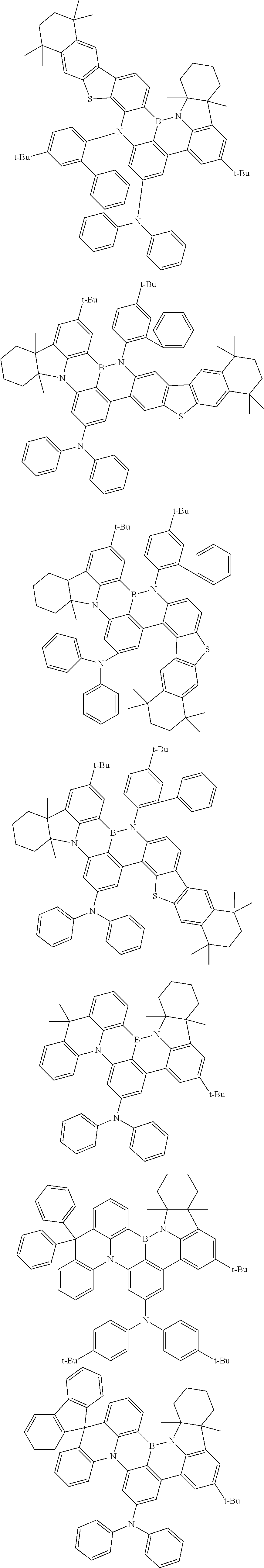 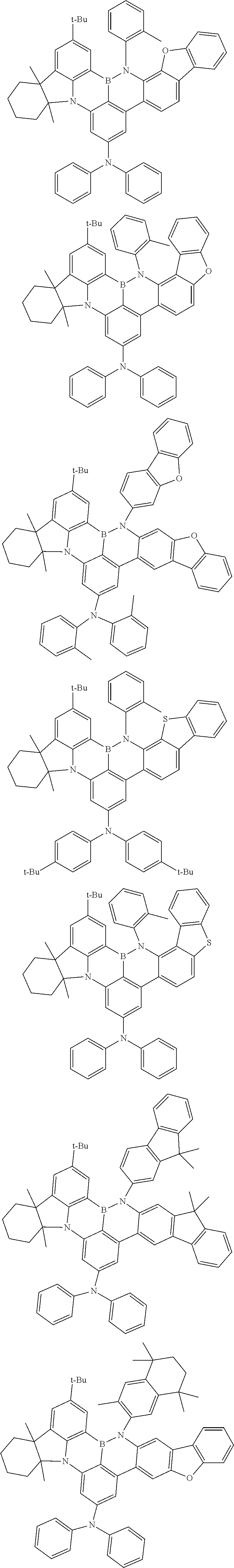 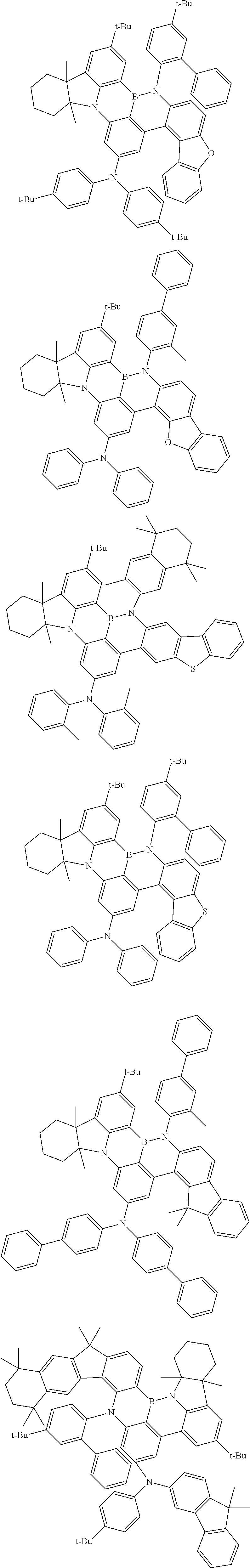 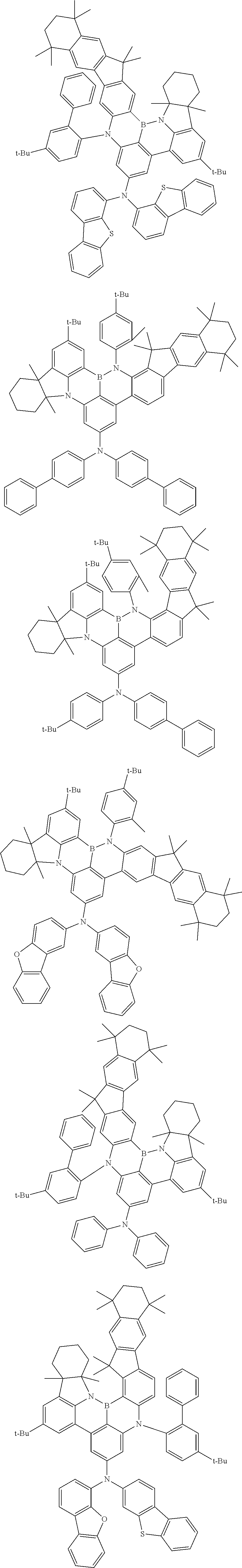 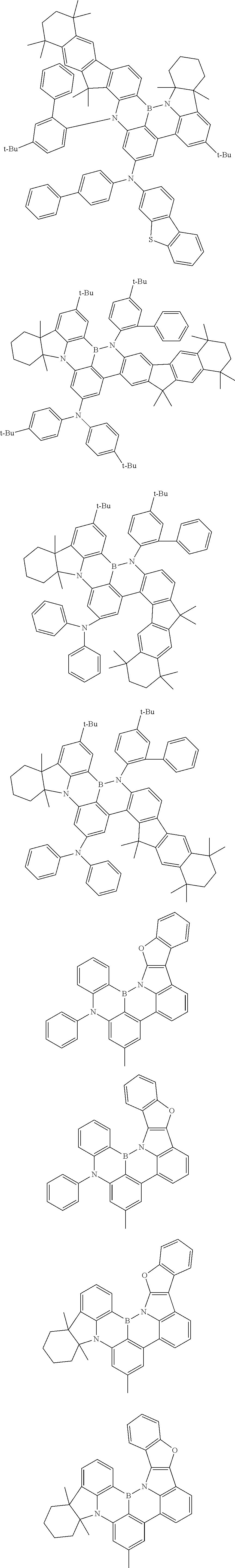 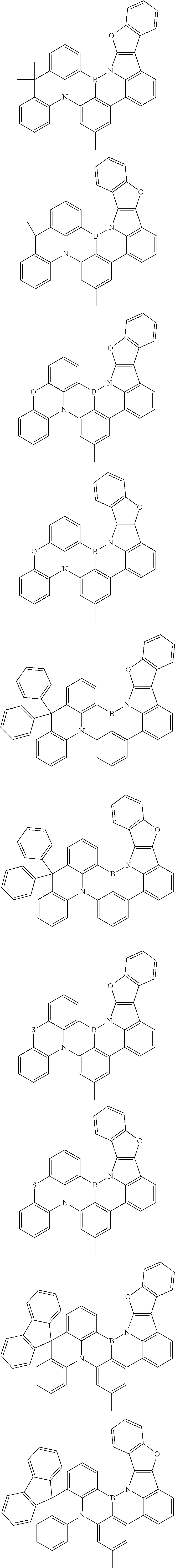 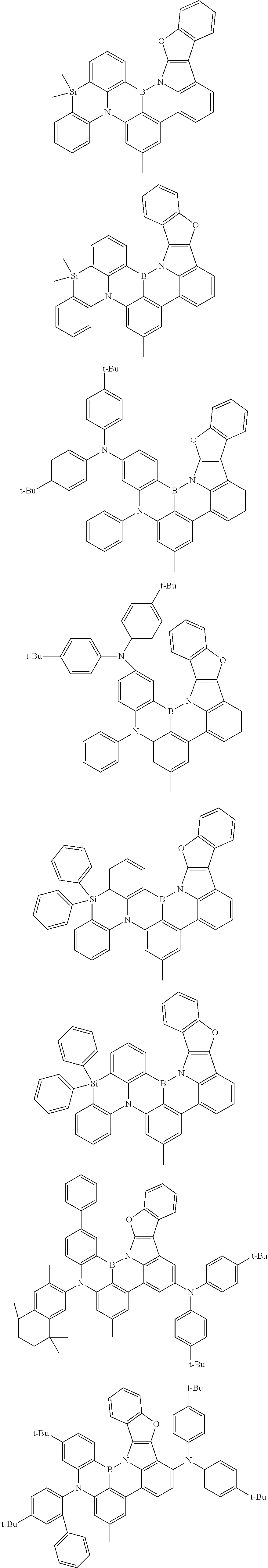 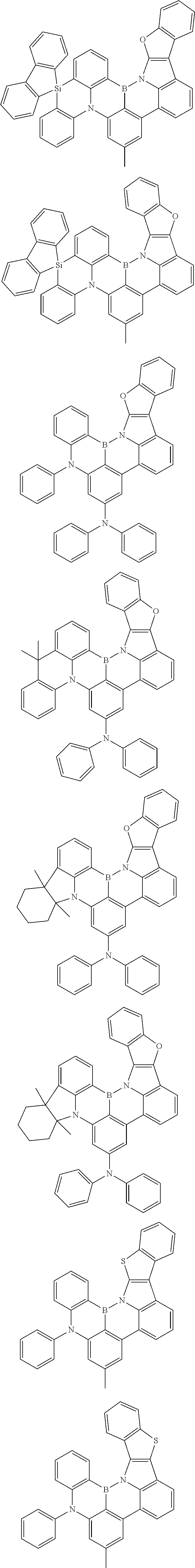 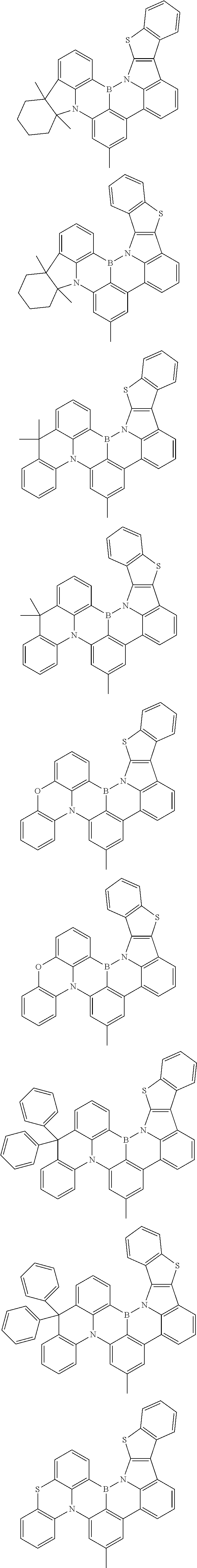 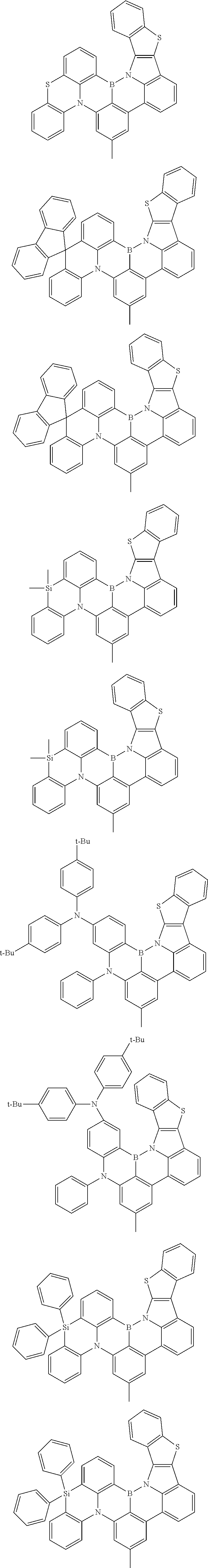 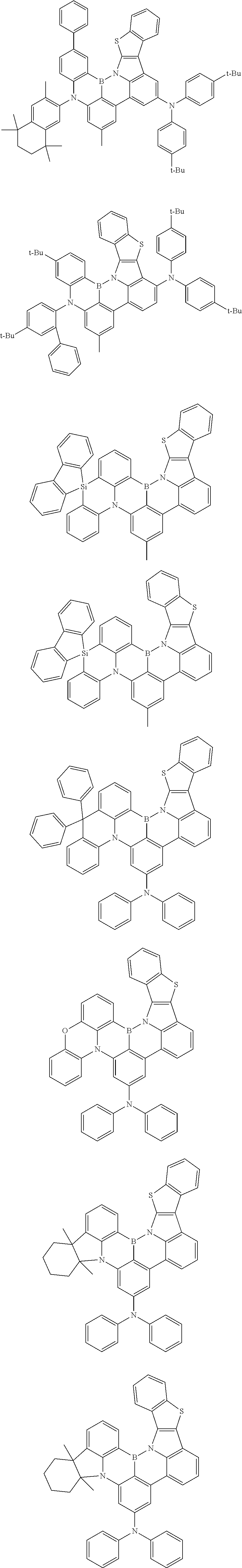 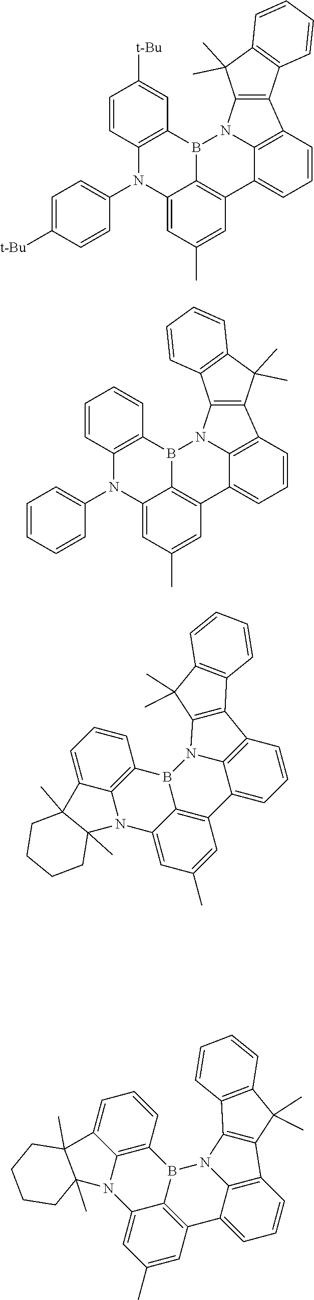 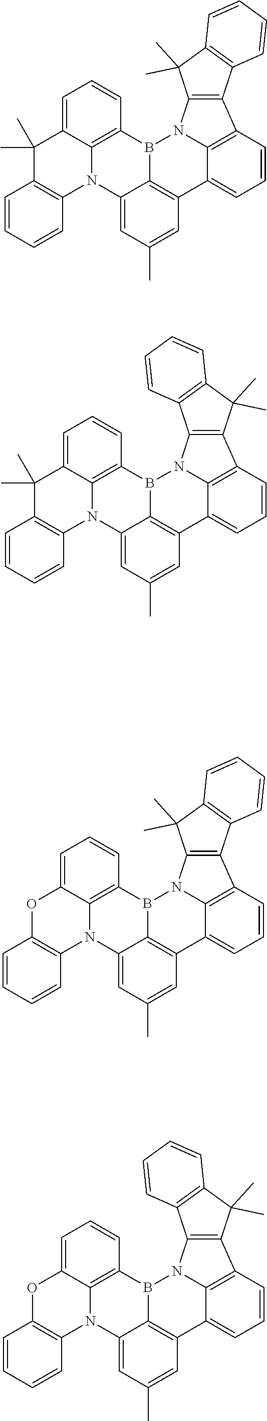 [SMILES: Cc1cc2c3c(c1)N1c4ccccc4C(C)(C)c4cccc(c41)B3n1c3c(c4cccc-2c41)-c1ccccc1C3(C)C ; Cc1cc2c3c(c1)N1c4ccccc4C(C)(C)c4cccc(c41)B3n1c3c(c4cccc-2c41)C(C)(C)c1ccccc1-3 ; Cc1cc2c3c(c1)N1c4ccccc4Oc4cccc(c41)B3n1c3c(c4cccc-2c41)-c1ccccc1C3(C)C ; Cc1cc2c3c(c1)N1c4ccccc4Oc4cccc(c41)B3n1c3c(c4cccc-2c41)C(C)(C)c1ccccc1-3] 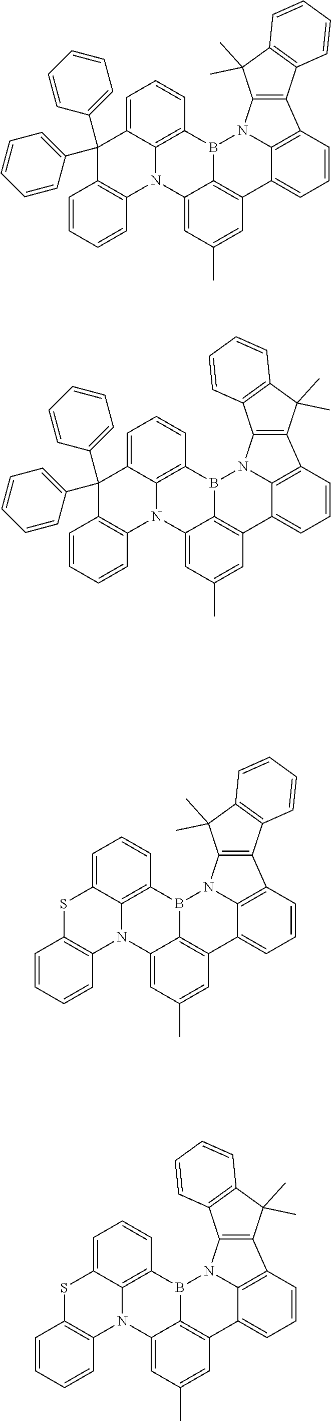 [SMILES: Cc1cc2c3c(c1)N1c4ccccc4C(c4ccccc4)(c4ccccc4)c4cccc(c41)B3n1c3c(c4cccc-2c41)-c1ccccc1C3(C)C ; Cc1cc2c3c(c1)N1c4ccccc4C(c4ccccc4)(c4ccccc4)c4cccc(c41)B3n1c3c(c4cccc-2c41)C(C)(C)c1ccccc1-3 ; Cc1cc2c3c(c1)N1c4ccccc4Sc4cccc(c41)B3n1c3c(c4cccc-2c41)-c1ccccc1C3(C)C ; Cc1cc2c3c(c1)N1c4ccccc4Sc4cccc(c41)B3n1c3c(c4cccc-2c41)C(C)(C)c1ccccc1-3] 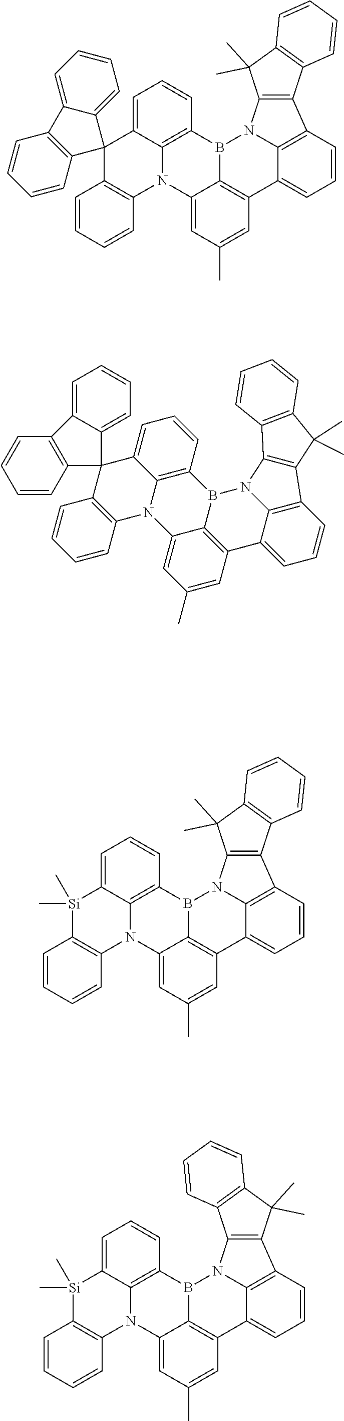 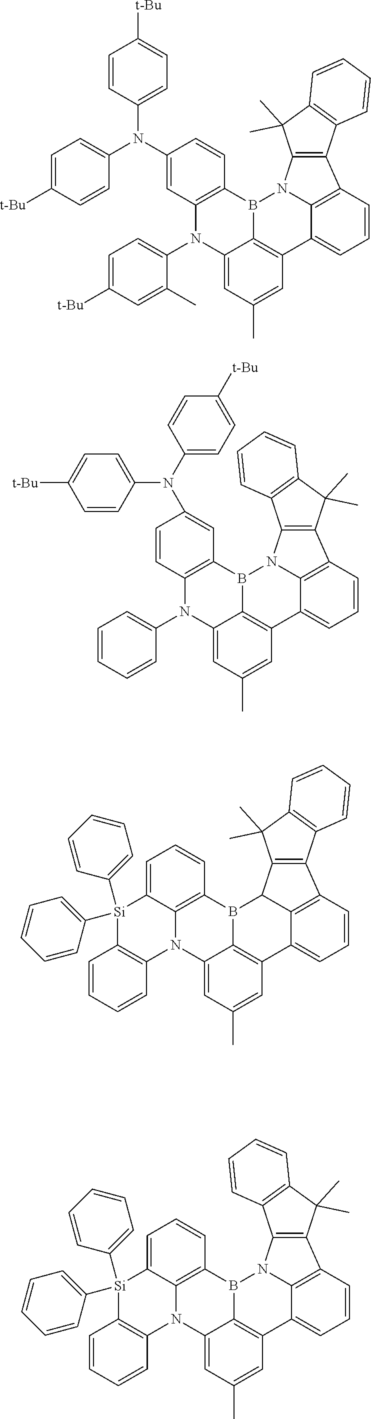 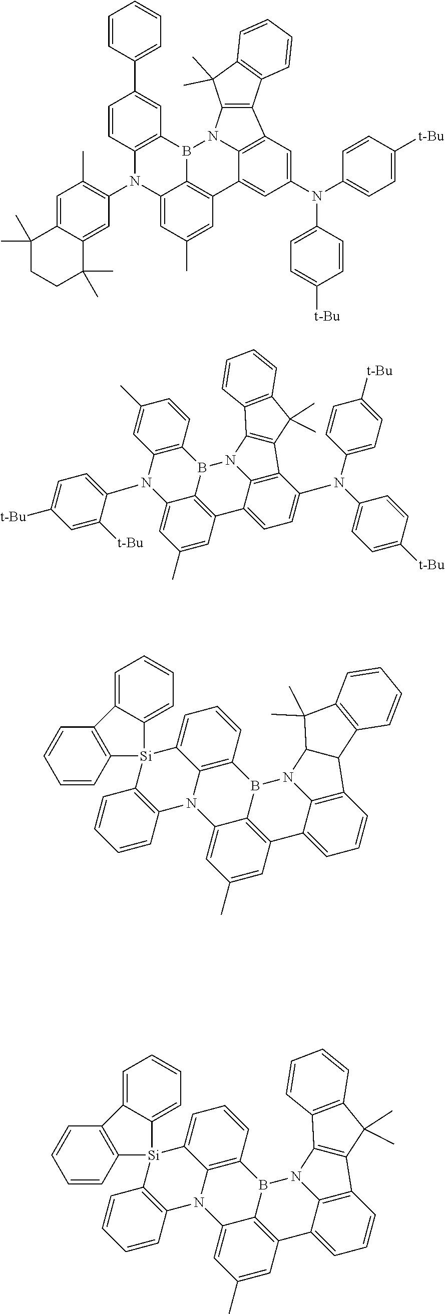 [SMILES: Cc1cc2c3c(c1)N(c1cc4c(cc1C)C(C)(C)CCC4(C)C)c1ccc(-c4ccccc4)cc1B3n1c3c(c4cc(N(c5ccc(C(C)(C)C)cc5)c5ccc(C(C)(C)C)cc5)cc-2c41)-c1ccccc1C3(C)C ; Cc1ccc2c(c1)N(c1ccc(C(C)(C)C)cc1C(C)(C)C)c1cc(C)cc3c1B2n1c2c(c4c(N(c5ccc(C(C)(C)C)cc5)c5ccc(C(C)(C)C)cc5)ccc-3c41)C(C)(C)c1ccccc1-2 ; Cc1cc2c3c(c1)N1c4ccccc4[Si]4(c5ccccc5-c5ccccc54)c4cccc(c41)B3N1c3c-2cccc3C2c3ccccc3C(C)(C)C21 ; Cc1cc2c3c(c1)N1c4ccccc4[Si]4(c5ccccc5-c5ccccc54)c4cccc(c41)B3n1c3c(c4cccc-2c41)C(C)(C)c1ccccc1-3] 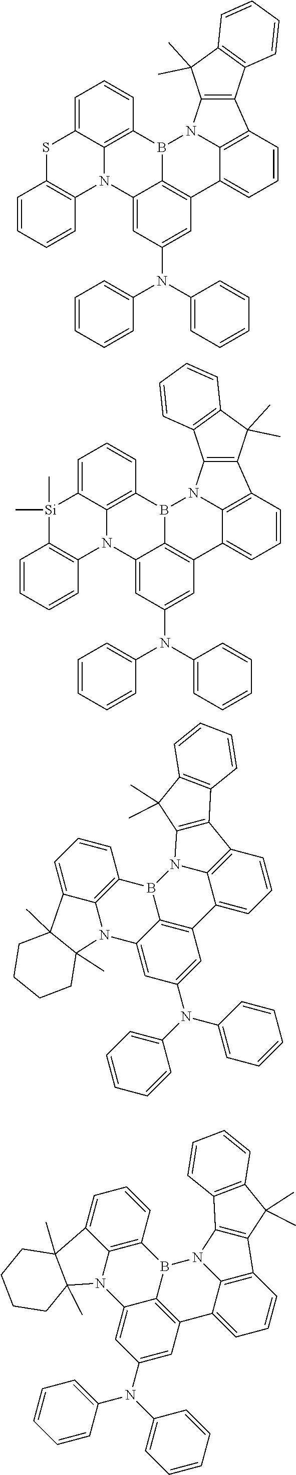 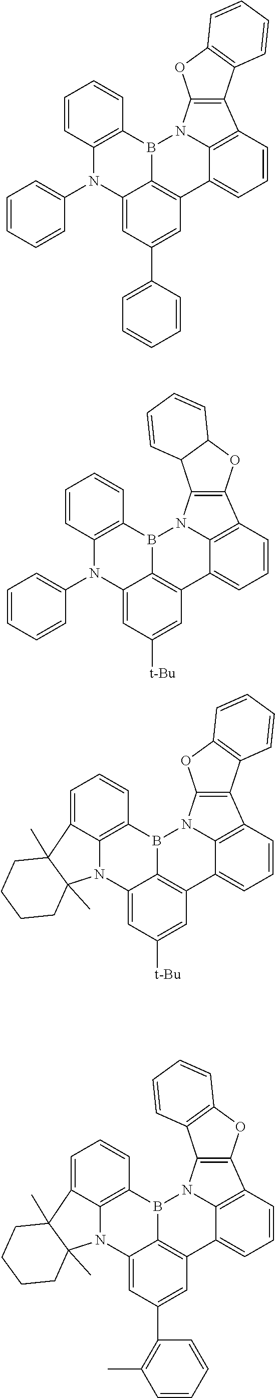 [SMILES: c1ccc(-c2cc3c4c(c2)N(c2ccccc2)c2ccccc2B4n2c4oc5ccccc5c4c4cccc-3c42)cc1 ; CC(C)(C)c1cc2c3c(c1)N(c1ccccc1)c1ccccc1B3n1c3c(c4cccc-2c41)OC1C=CC=CC31 ; CC(C)(C)c1cc2c3c(c1)N1c4c(cccc4C4(C)CCCCC14C)B3n1c3oc4ccccc4c3c3cccc-2c31 ; Cc1ccccc1-c1cc2c3c(c1)N1c4c(cccc4C4(C)CCCCC14C)B3n1c3c-2cccc3c2oc3ccccc3c21] 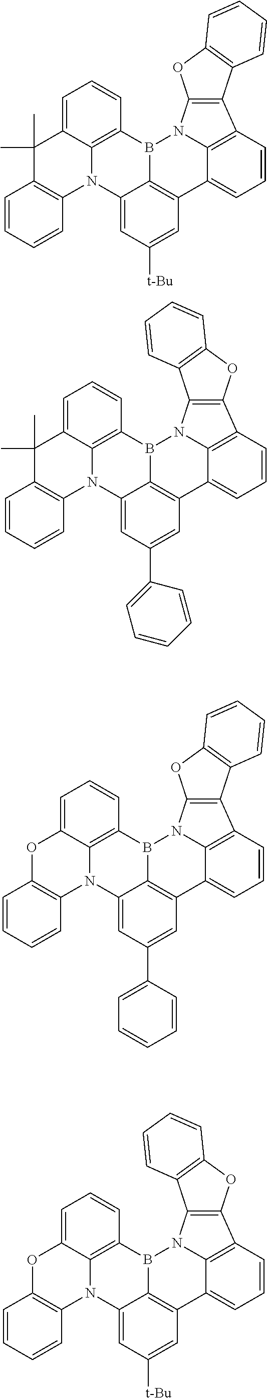 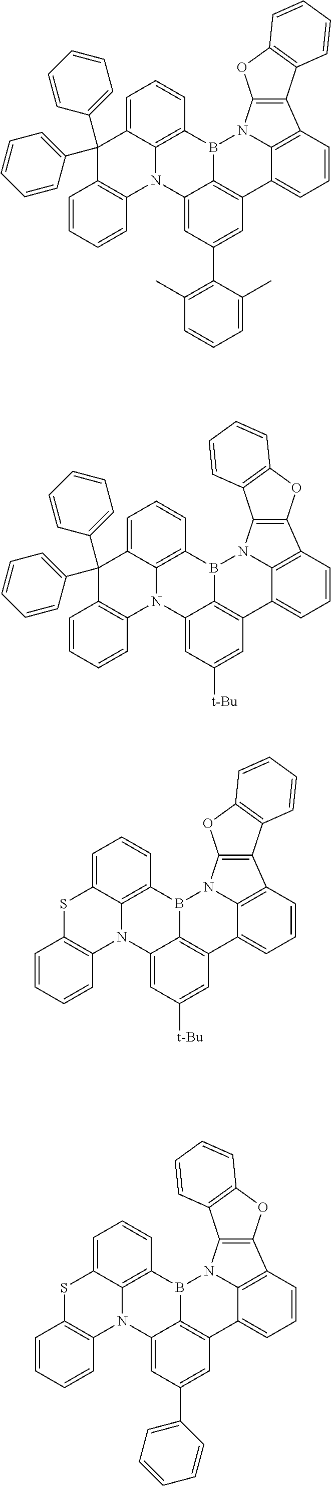 [SMILES: Cc1cccc(C)c1-c1cc2c3c(c1)N1c4ccccc4C(c4ccccc4)(c4ccccc4)c4cccc(c41)B3n1c3oc4ccccc4c3c3cccc-2c31 ; CC(C)(C)c1cc2c3c(c1)N1c4ccccc4C(c4ccccc4)(c4ccccc4)c4cccc(c41)B3n1c3c-2cccc3c2oc3ccccc3c21 ; CC(C)(C)c1cc2c3c(c1)N1c4ccccc4Sc4cccc(c41)B3n1c3oc4ccccc4c3c3cccc-2c31 ; c1ccc(-c2cc3c4c(c2)N2c5ccccc5Sc5cccc(c52)B4n2c4c-3cccc4c3oc4ccccc4c32)cc1] 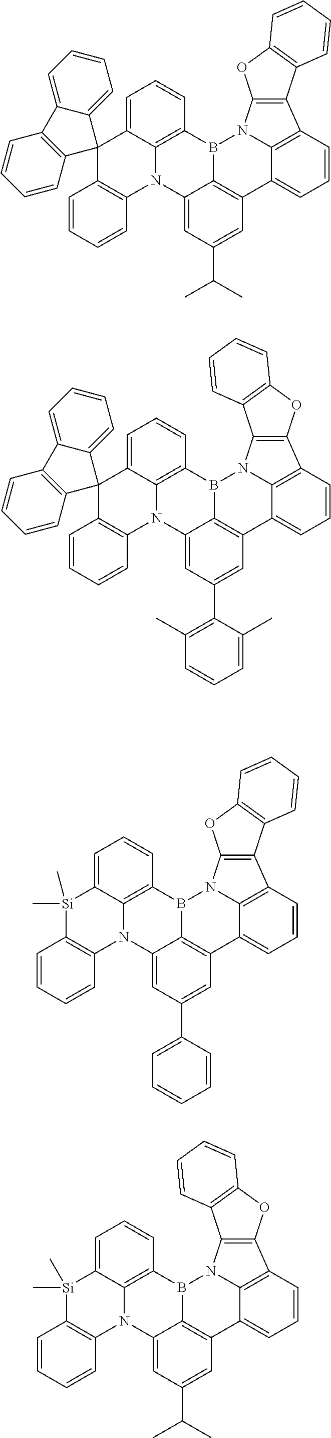 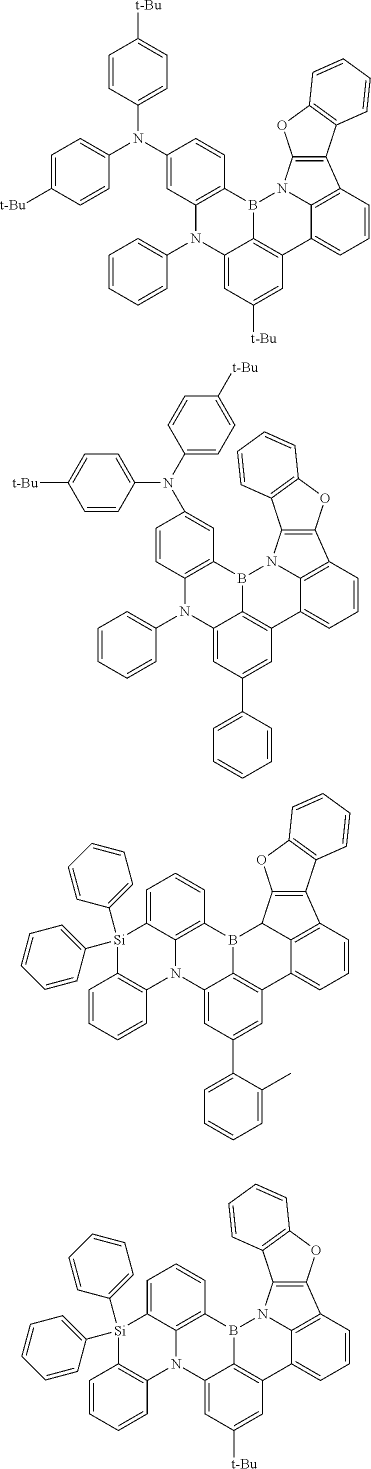 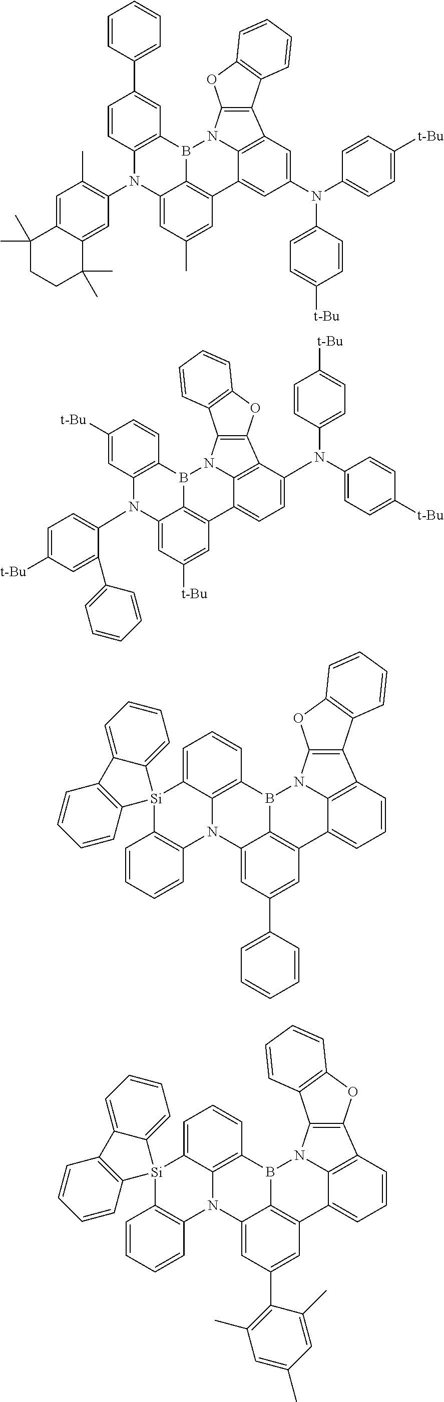 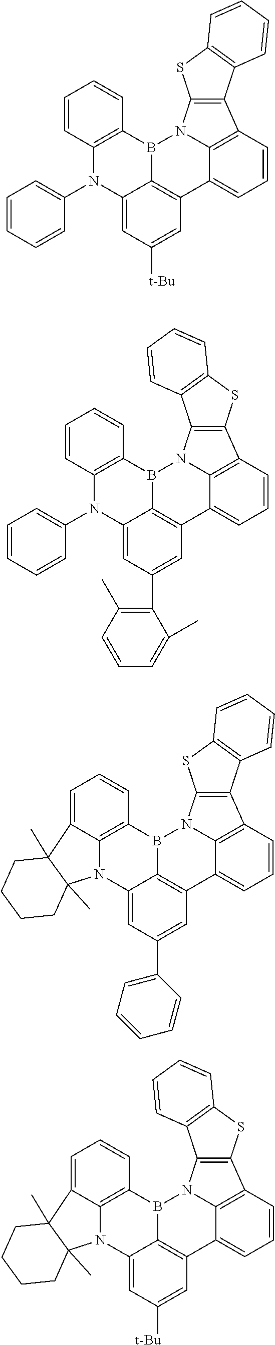 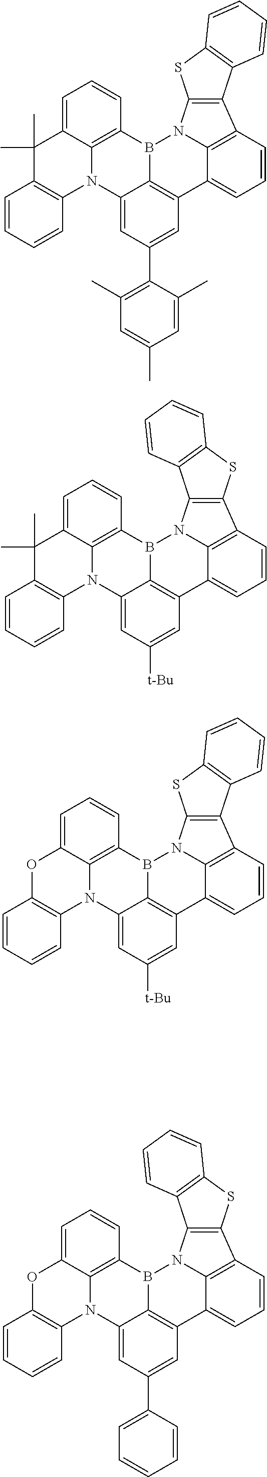 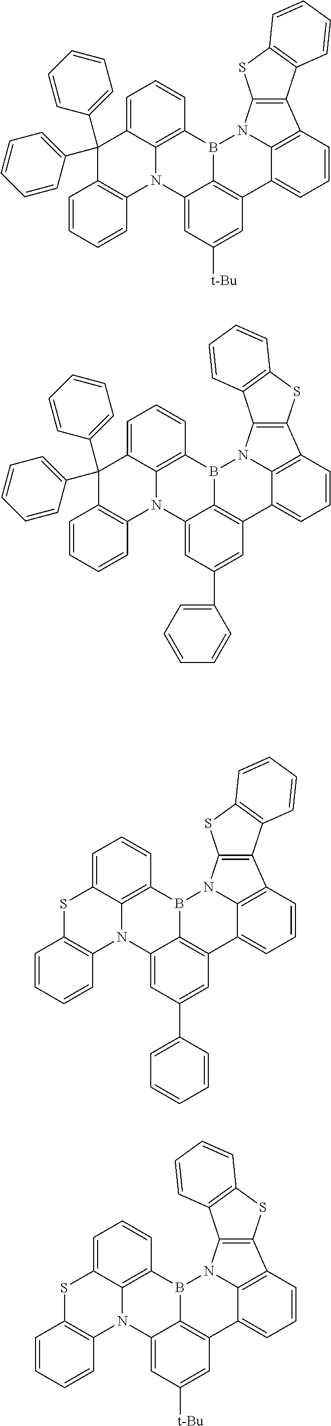 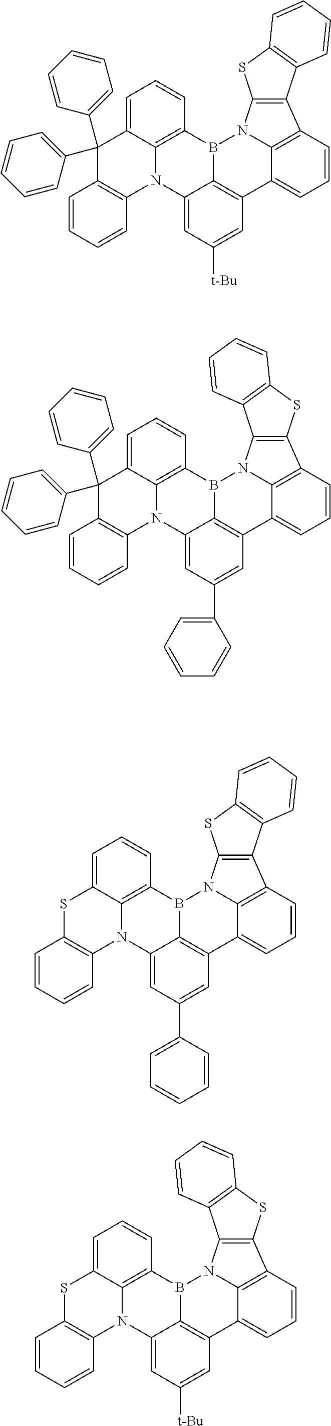 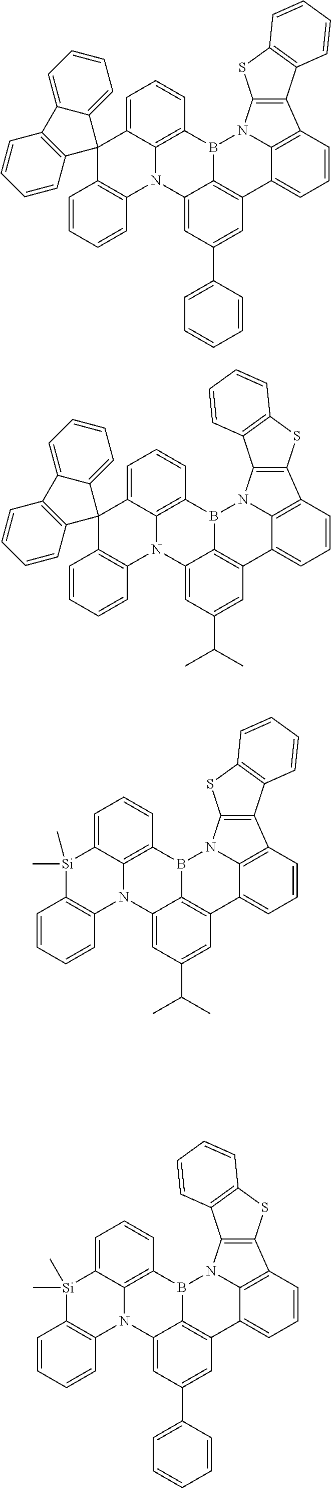 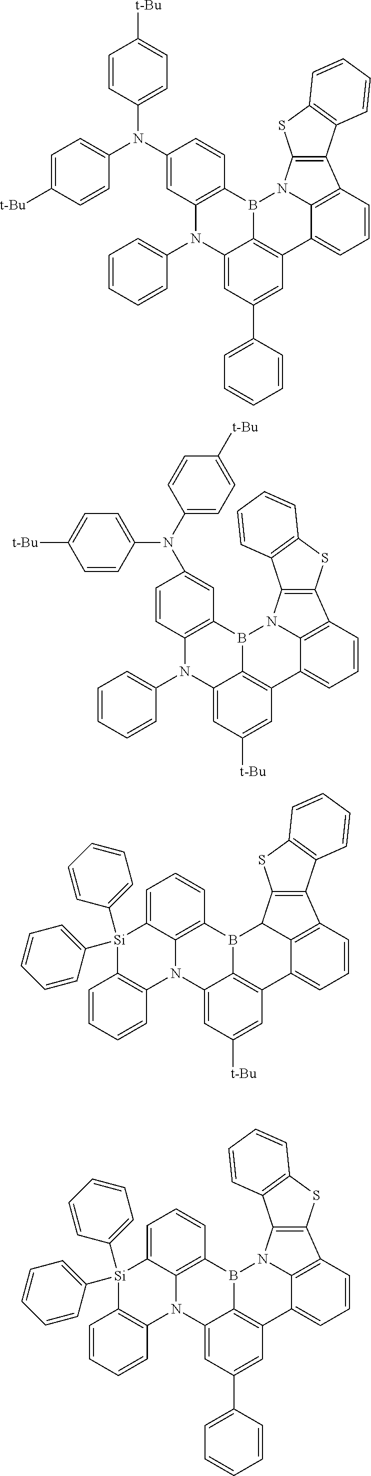 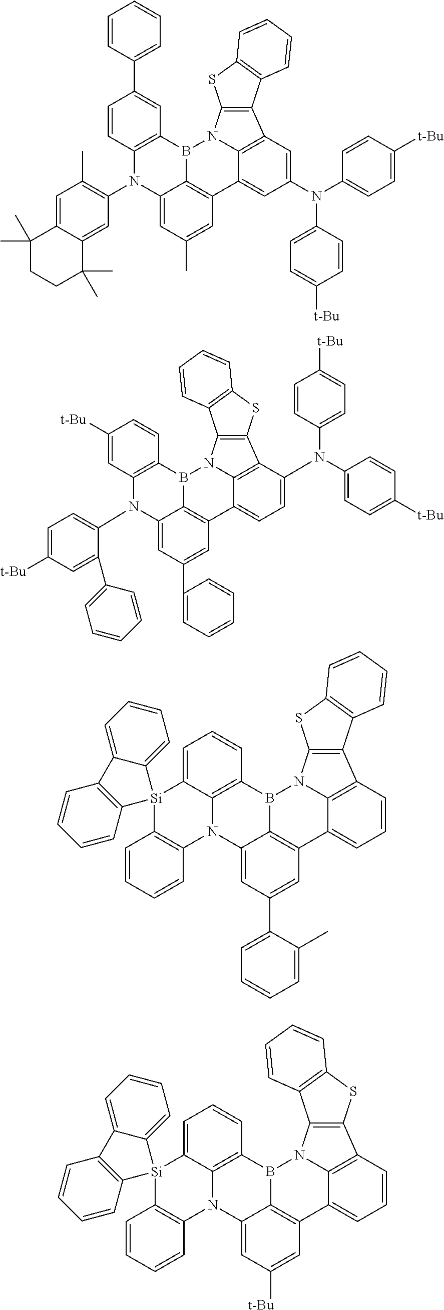 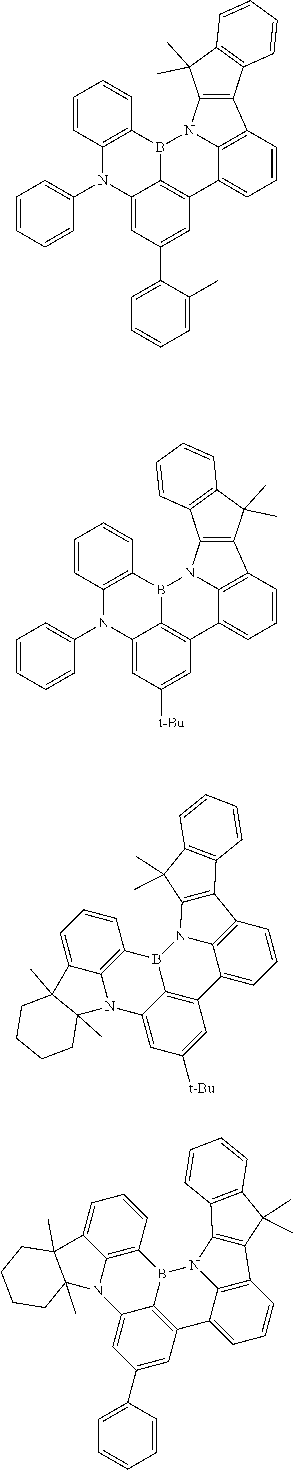 [SMILES: Cc1ccccc1-c1cc2c3c(c1)N(c1ccccc1)c1ccccc1B3n1c3c(c4cccc-2c41)-c1ccccc1C3(C)C ; CC(C)(C)c1cc2c3c(c1)N(c1ccccc1)c1ccccc1B3n1c3c(c4cccc-2c41)C(C)(C)c1ccccc1-3 ; CC(C)(C)c1cc2c3c(c1)N1c4c(cccc4C4(C)CCCCC14C)B3n1c3c(c4cccc-2c41)-c1ccccc1C3(C)C ; CC1(C)c2ccccc2-c2c1c1cccc3c1n2B1c2cccc4c2N(c2cc(-c5ccccc5)cc-3c21)C1(C)CCCCC41C] 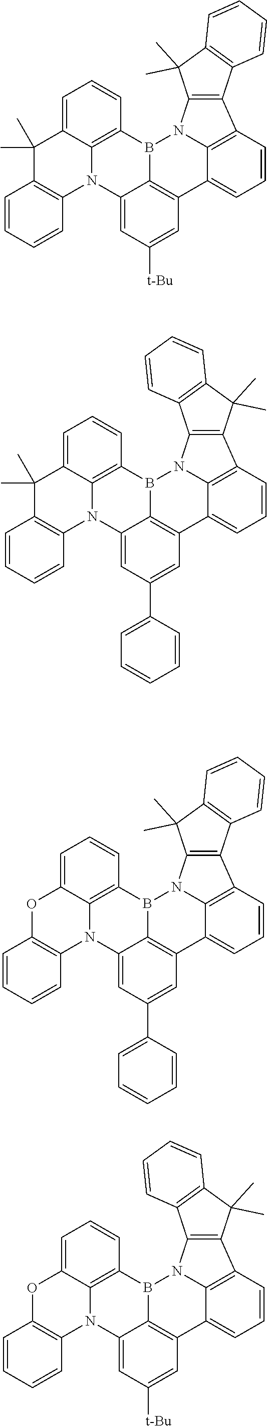 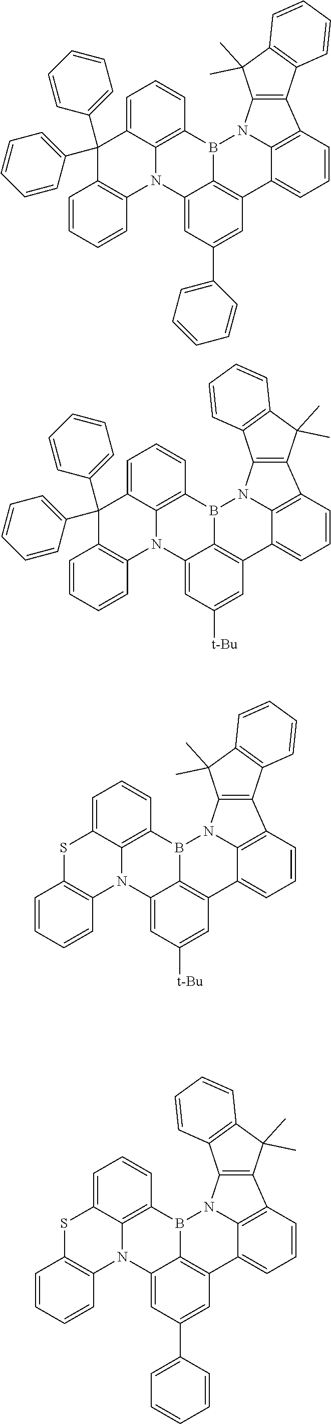 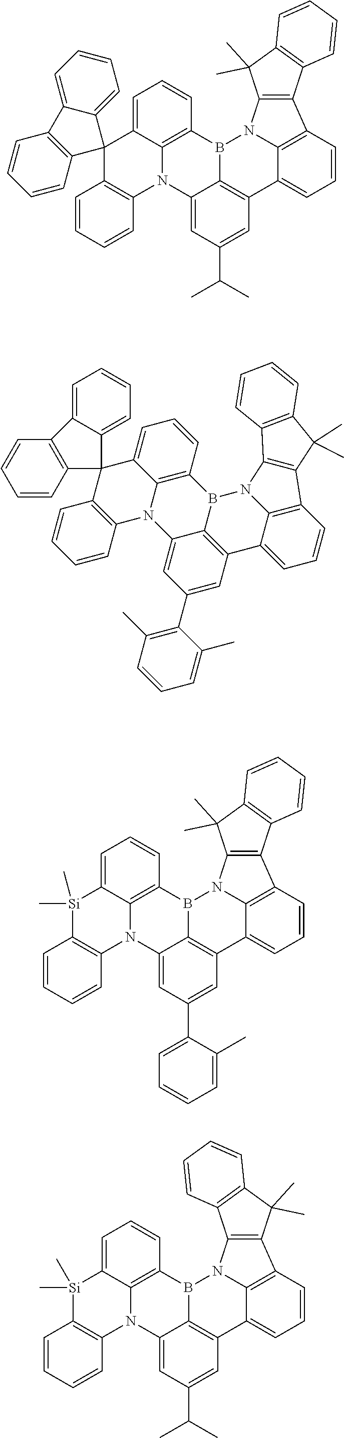 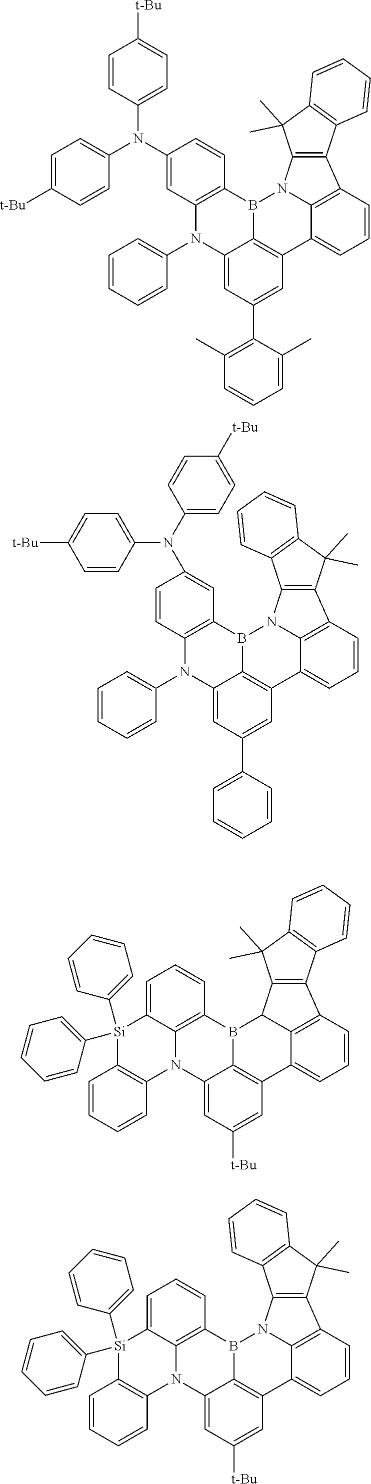 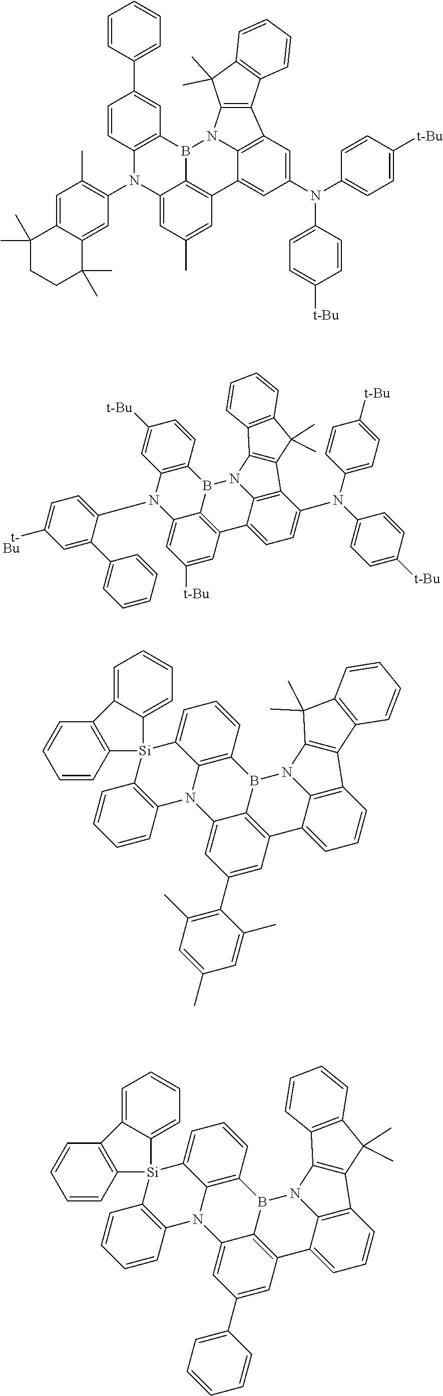 [SMILES: Cc1cc2c3c(c1)N(c1cc4c(cc1C)C(C)(C)CCC4(C)C)c1ccc(-c4ccccc4)cc1B3n1c3c(c4cc(N(c5ccc(C(C)(C)C)cc5)c5ccc(C(C)(C)C)cc5)cc-2c41)-c1ccccc1C3(C)C ; CC(C)(C)c1ccc(N(c2ccc(C(C)(C)C)cc2)c2ccc3c4c2c2c(n4B4c5ccc(C(C)(C)C)cc5N(c5ccc(C(C)(C)C)cc5-c5ccccc5)c5cc(C(C)(C)C)cc-3c54)-c3ccccc3C2(C)C)cc1 ; Cc1cc(C)c(-c2cc3c4c(c2)N2c5ccccc5[Si]5(c6ccccc6-c6ccccc65)c5cccc(c52)B4n2c4c(c5cccc-3c52)-c2ccccc2C4(C)C)c(C)c1 ; CC1(C)c2ccccc2-c2c1c1cccc3c1n2B1c2cccc4c2N(c2ccccc2[Si]42c4ccccc4-c4ccccc42)c2cc(-c4ccccc4)cc-3c21] 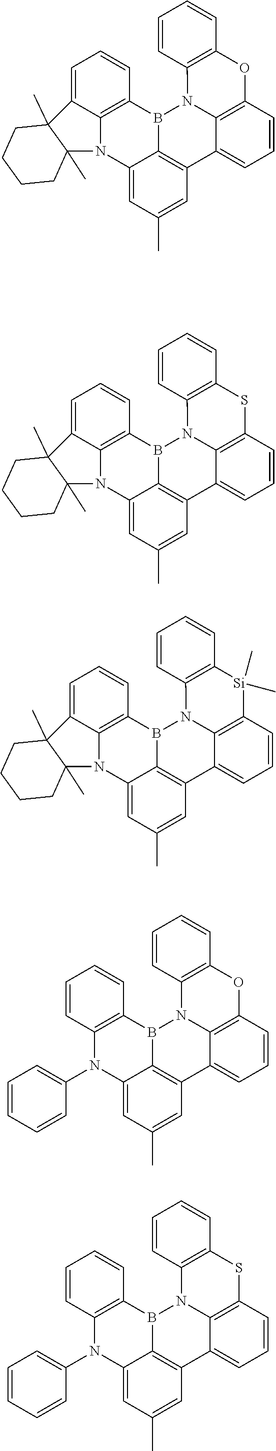 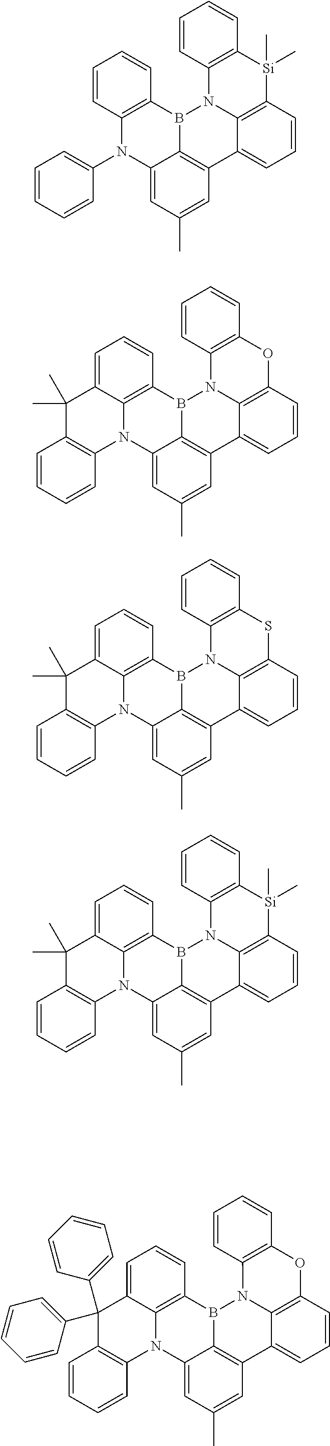 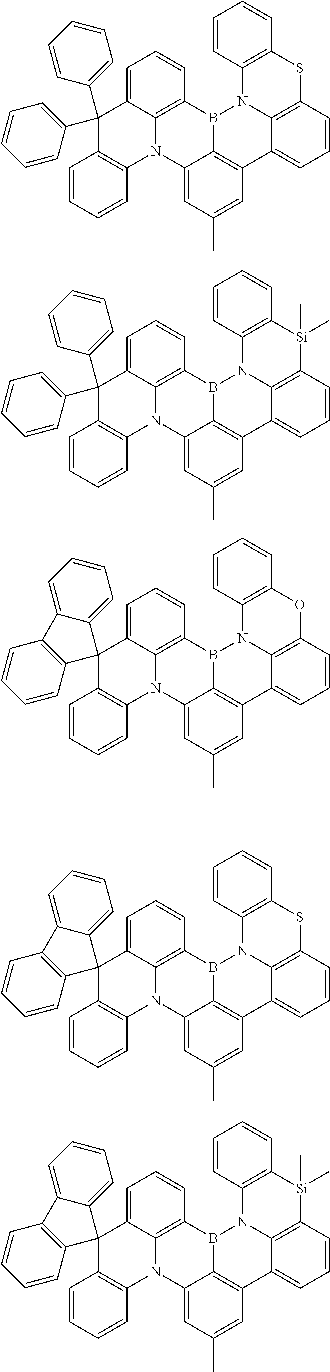 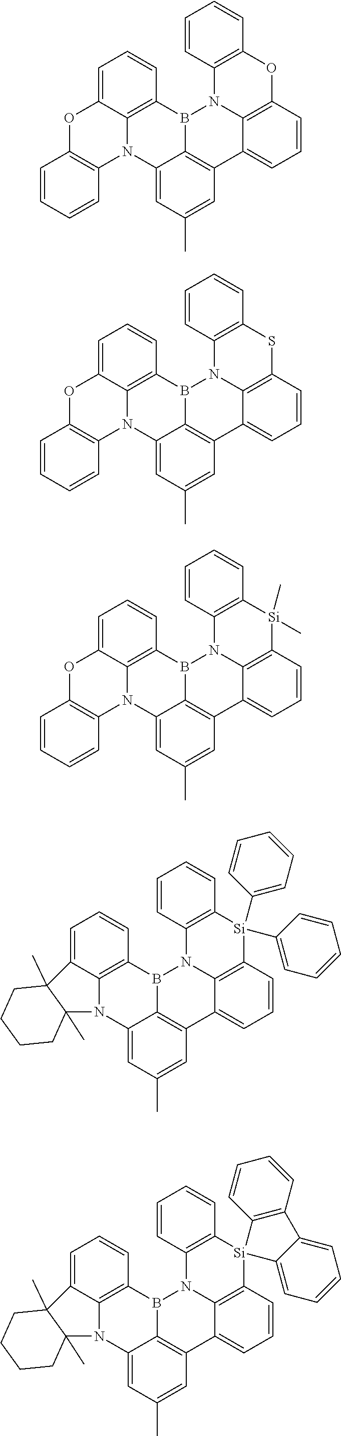 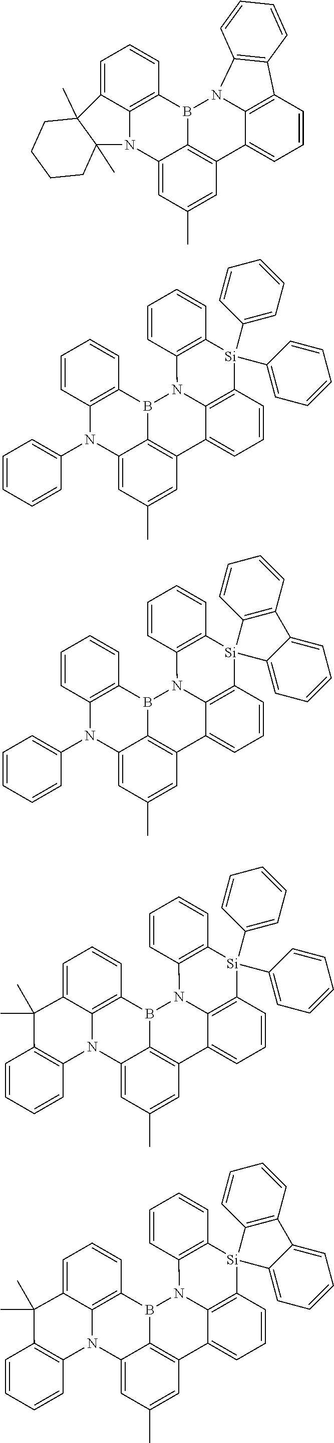 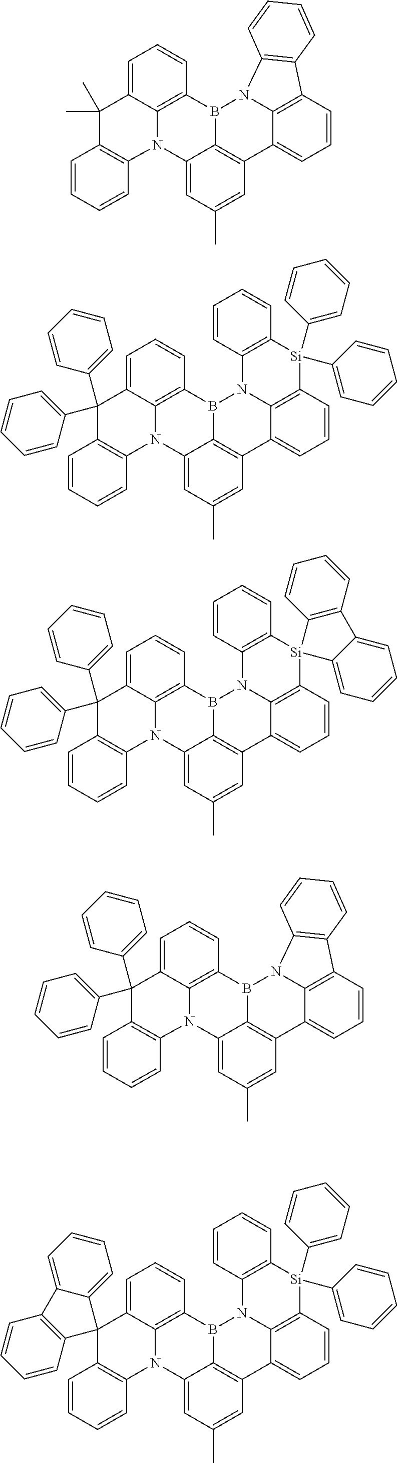 [SMILES: Cc1cc2c3c(c1)N1c4ccccc4C(C)(C)c4cccc(c41)B3n1c3ccccc3c3cccc-2c31 ; Cc1cc2c3c(c1)N1c4ccccc4C(c4ccccc4)(c4ccccc4)c4cccc(c41)B3N1c3ccccc3[Si](c3ccccc3)(c3ccccc3)c3cccc-2c31 ; Cc1cc2c3c(c1)N1c4ccccc4C(c4ccccc4)(c4ccccc4)c4cccc(c41)B3N1c3ccccc3[Si]3(c4ccccc4-c4ccccc43)c3cccc-2c31 ; Cc1cc2c3c(c1)N1c4ccccc4C(c4ccccc4)(c4ccccc4)c4cccc(c41)B3n1c3ccccc3c3cccc-2c31 ; Cc1cc2c3c(c1)N1c4ccccc4C4(c5ccccc5-c5ccccc54)c4cccc(c41)B3N1c3ccccc3[Si](c3ccccc3)(c3ccccc3)c3cccc-2c31] 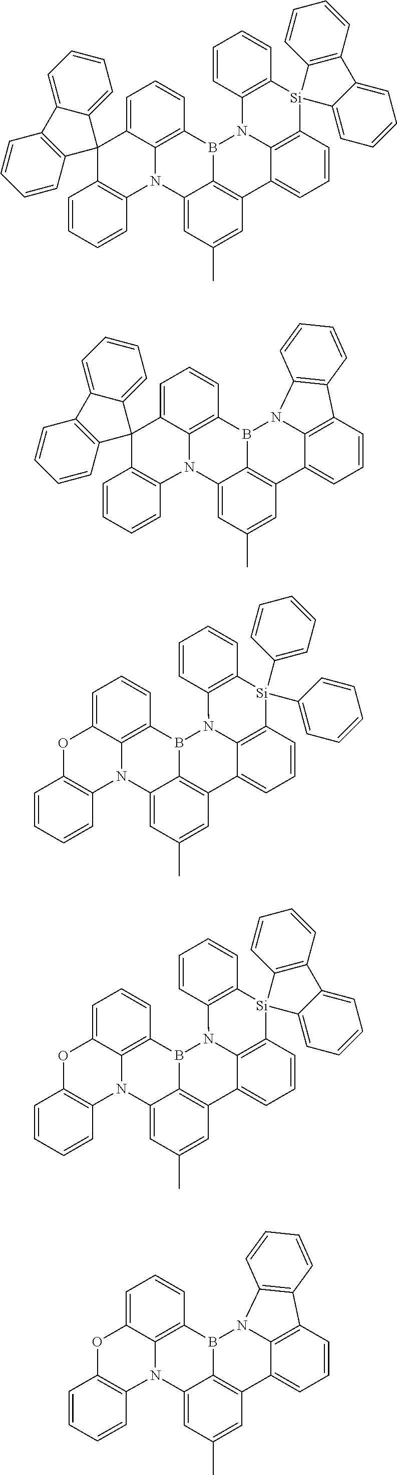 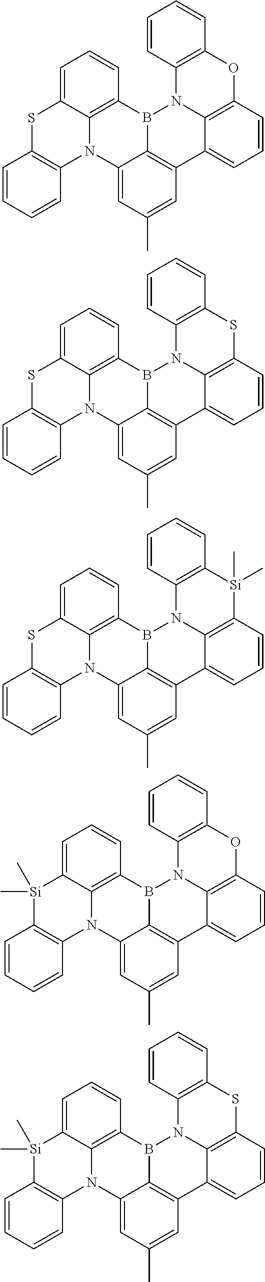 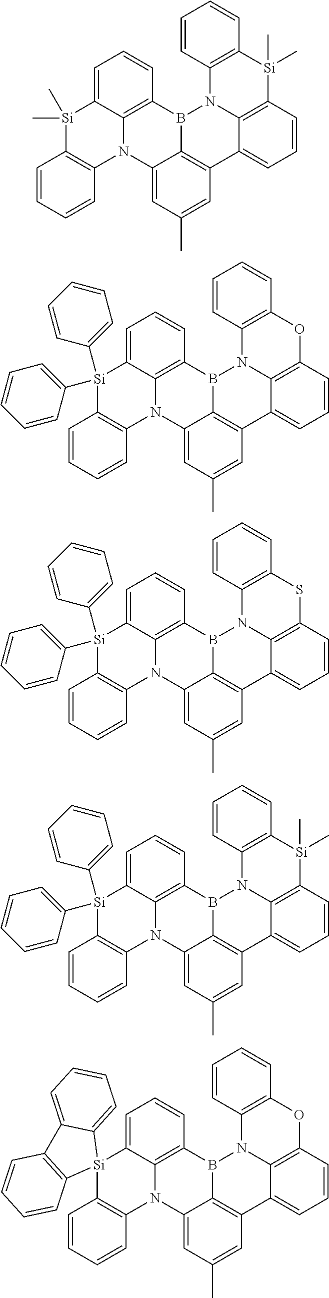 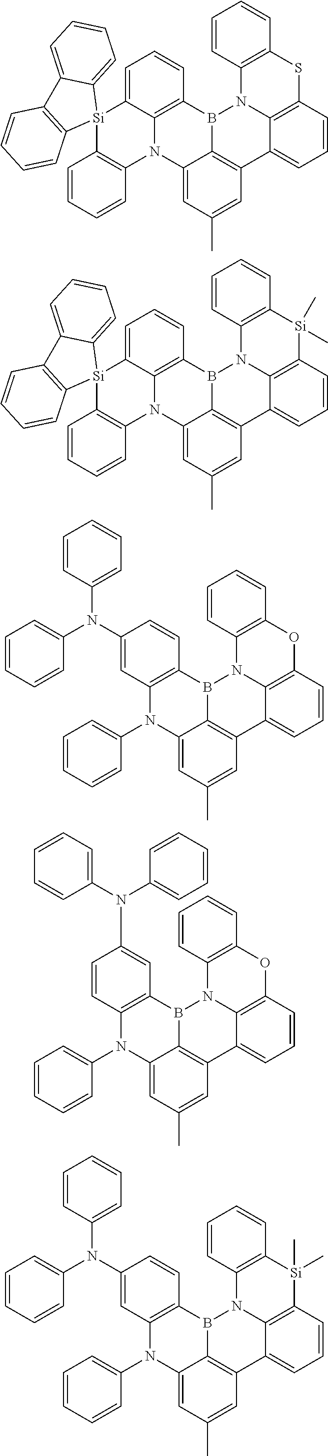 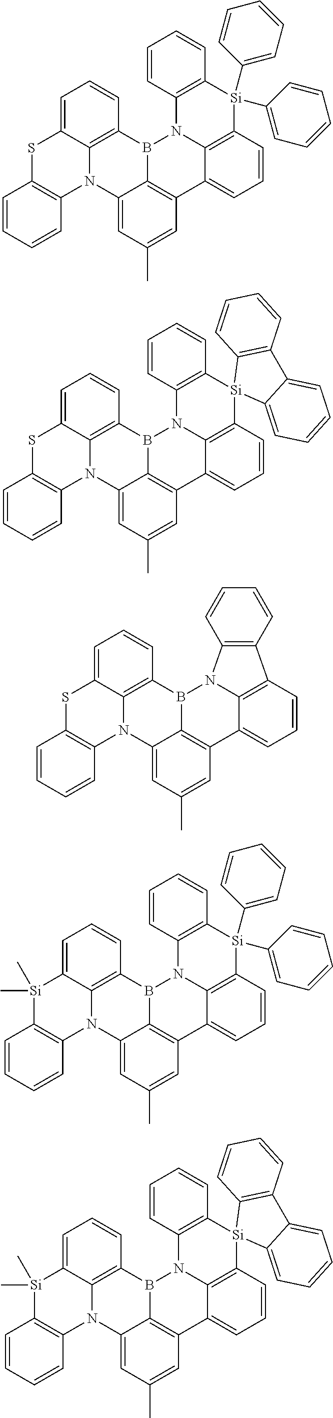 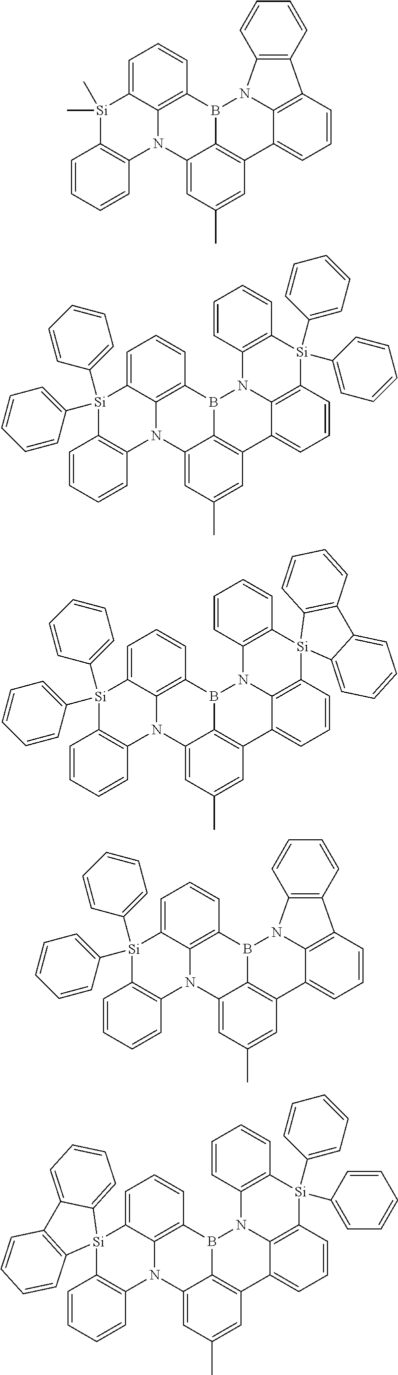 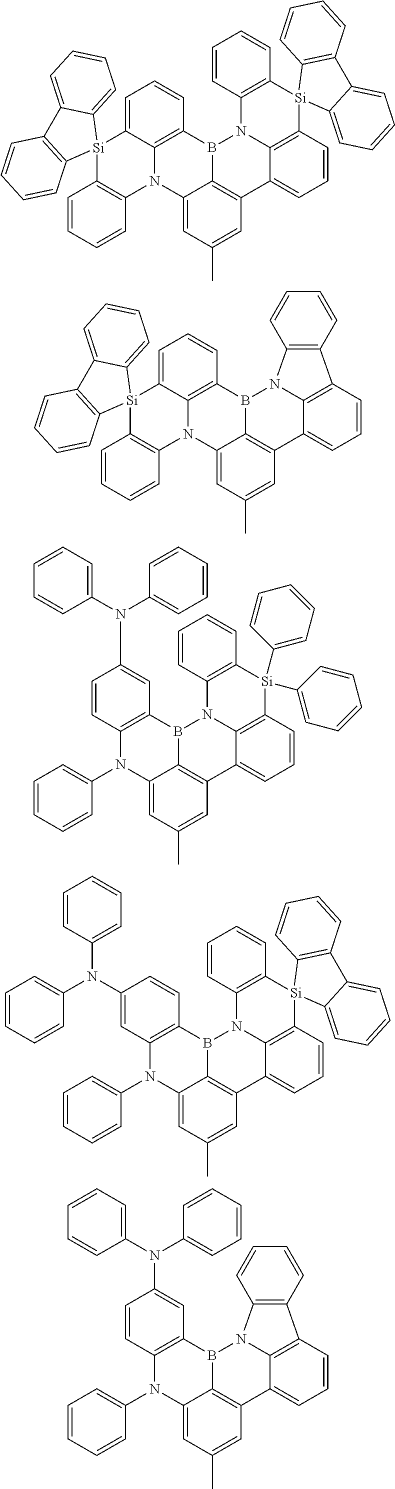 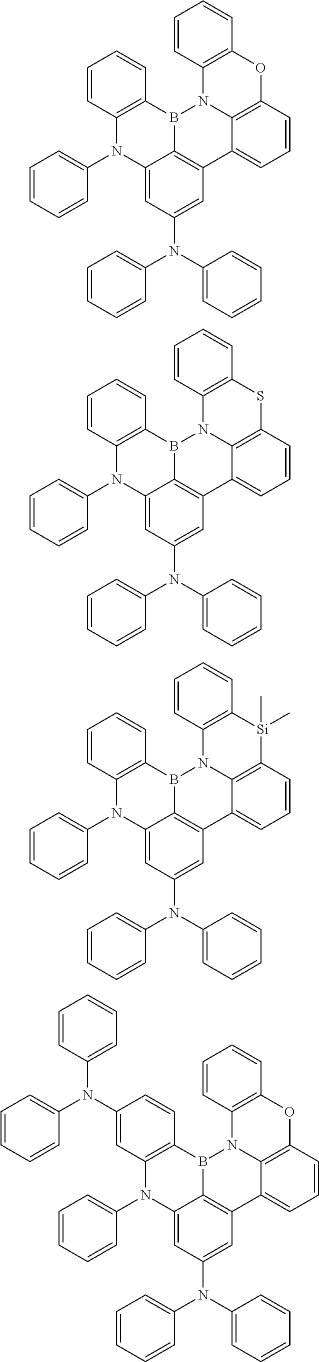 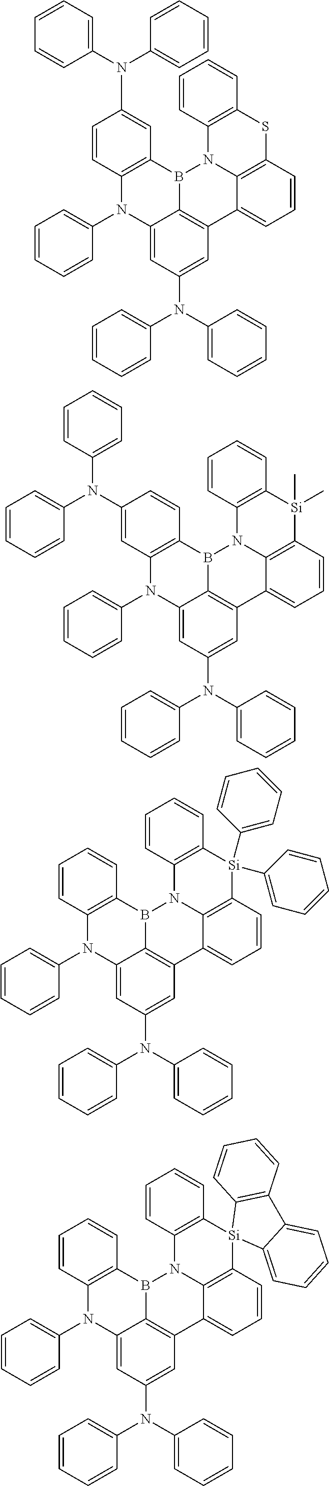 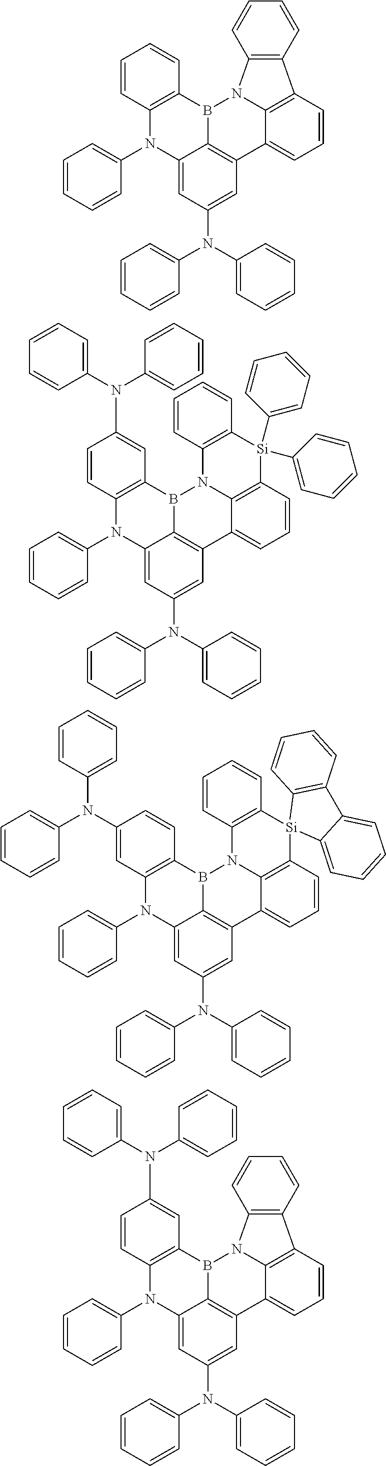 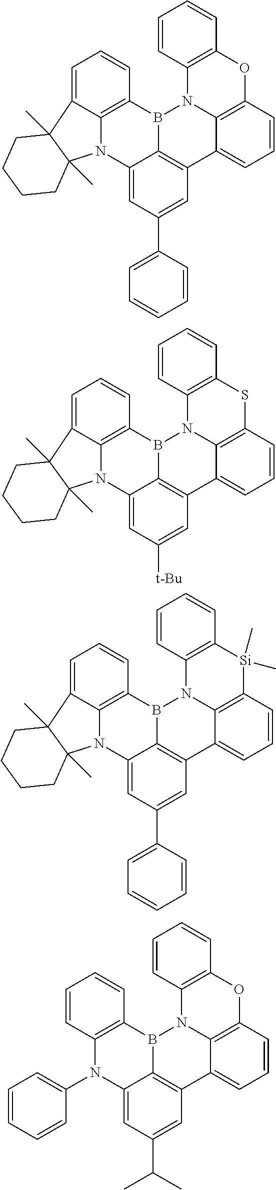 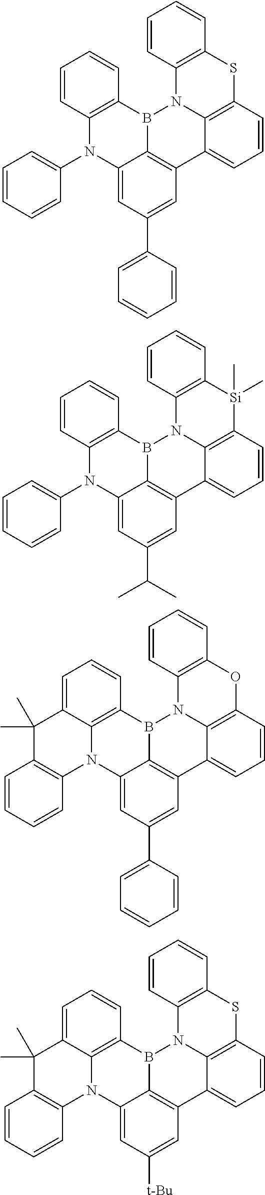 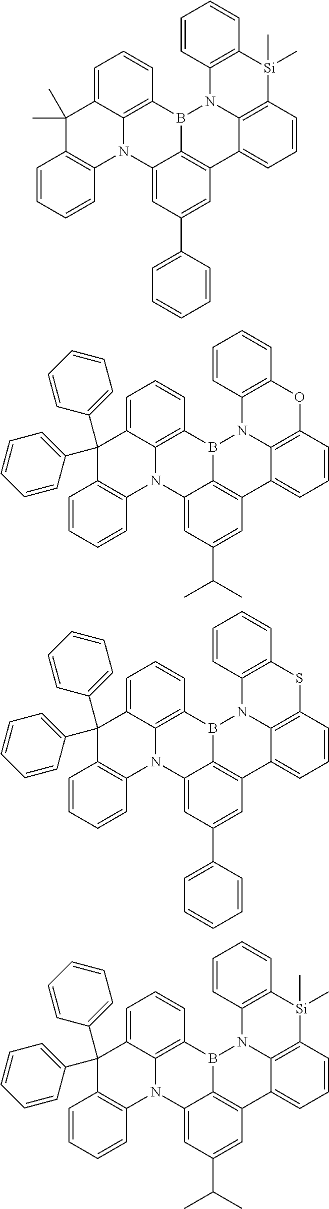 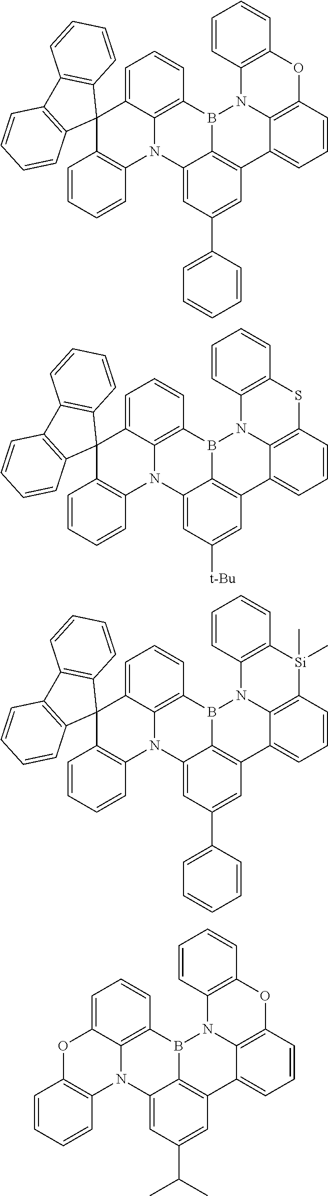 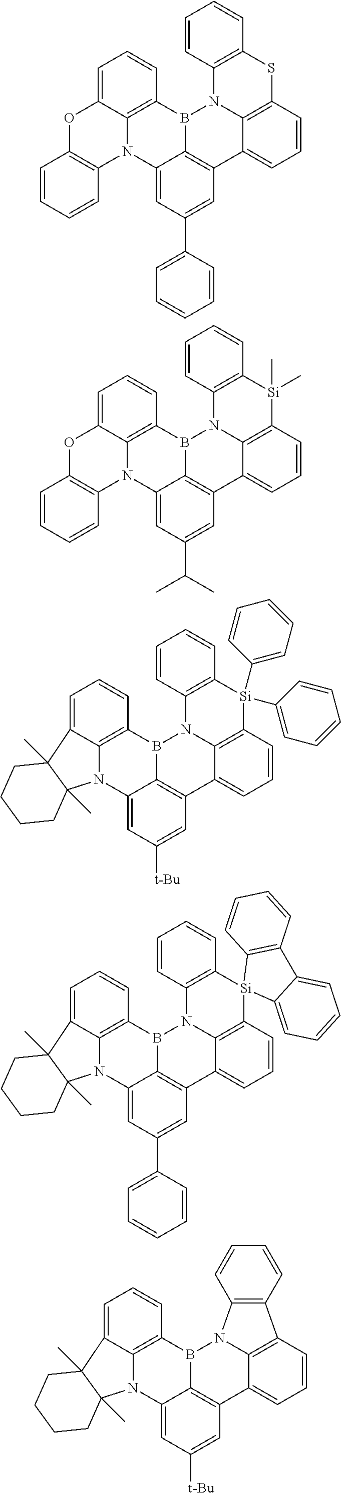 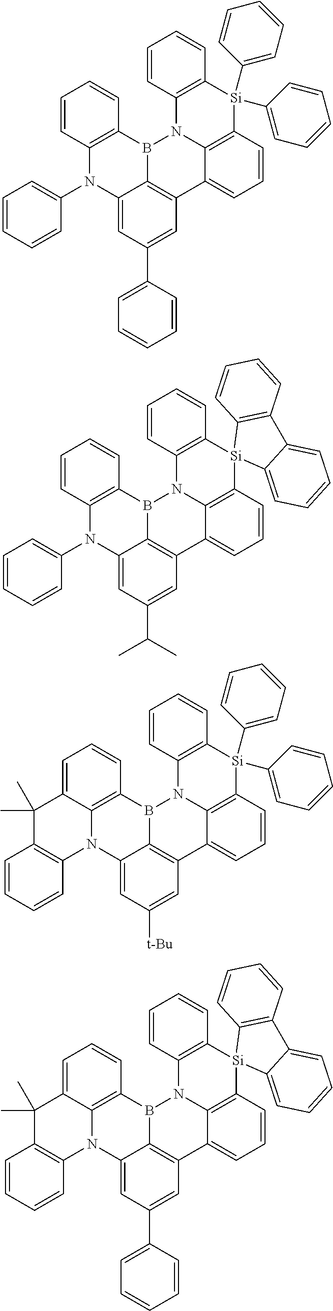 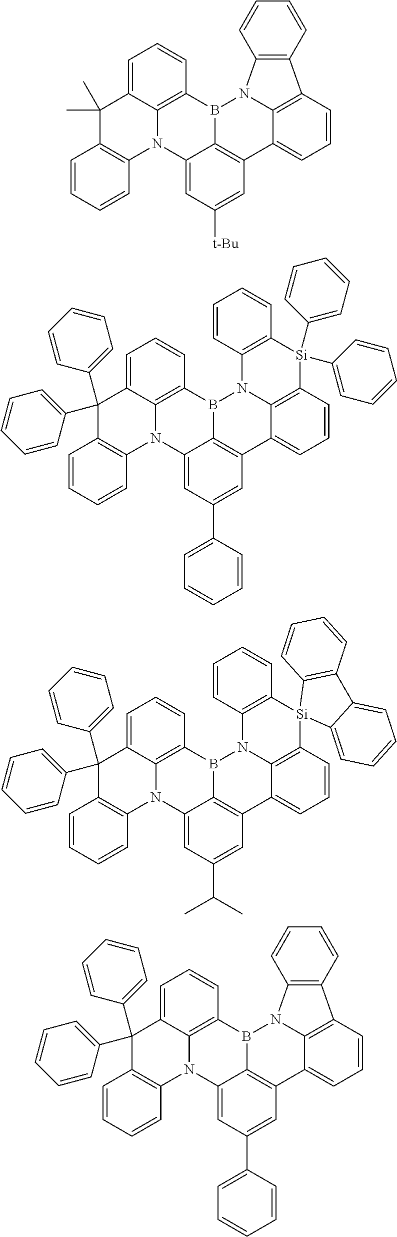 [SMILES: CC(C)(C)c1cc2c3c(c1)N1c4ccccc4C(C)(C)c4cccc(c41)B3n1c3ccccc3c3cccc-2c31 ; c1ccc(-c2cc3c4c(c2)N2c5ccccc5C(c5ccccc5)(c5ccccc5)c5cccc(c52)B4N2c4ccccc4[Si](c4ccccc4)(c4ccccc4)c4cccc-3c42)cc1 ; CC(C)c1cc2c3c(c1)N1c4ccccc4C(c4ccccc4)(c4ccccc4)c4cccc(c41)B3N1c3ccccc3[Si]3(c4ccccc4-c4ccccc43)c3cccc-2c31 ; c1ccc(-c2cc3c4c(c2)N2c5ccccc5C(c5ccccc5)(c5ccccc5)c5cccc(c52)B4n2c4ccccc4c4cccc-3c42)cc1] 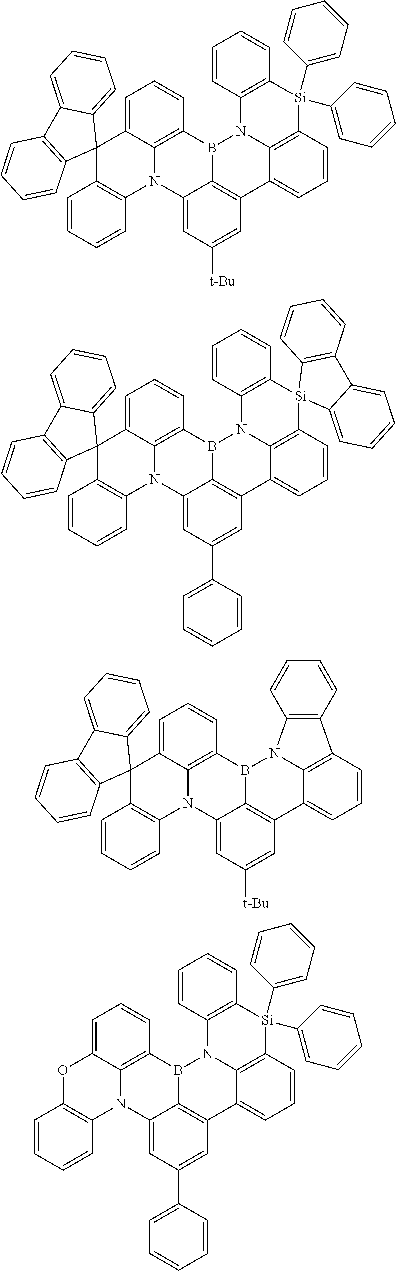 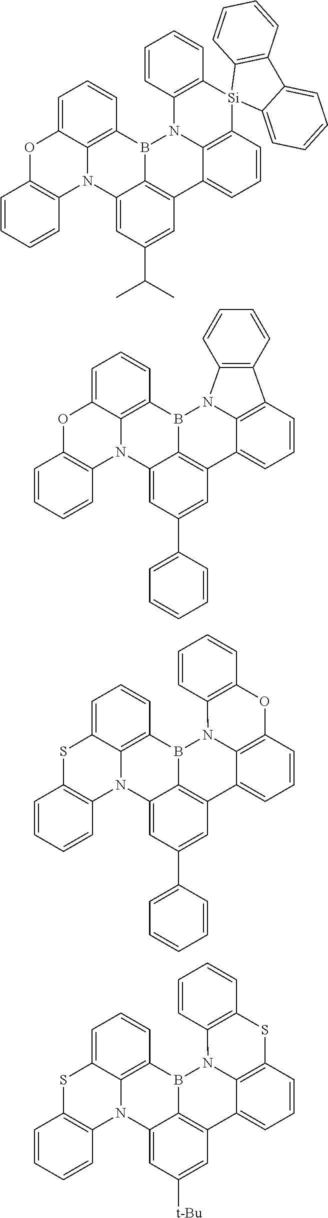 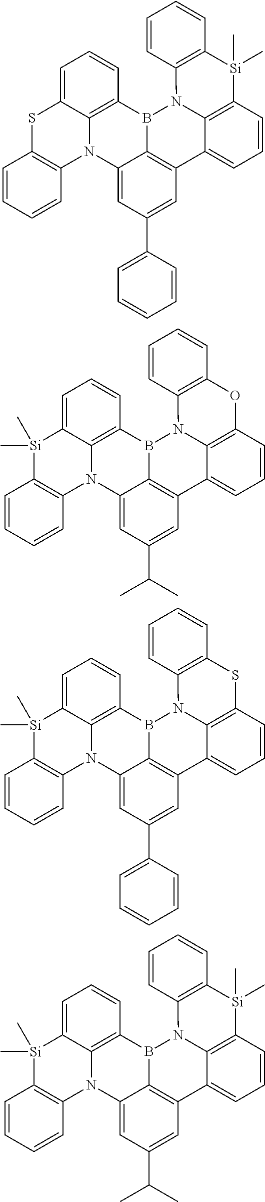 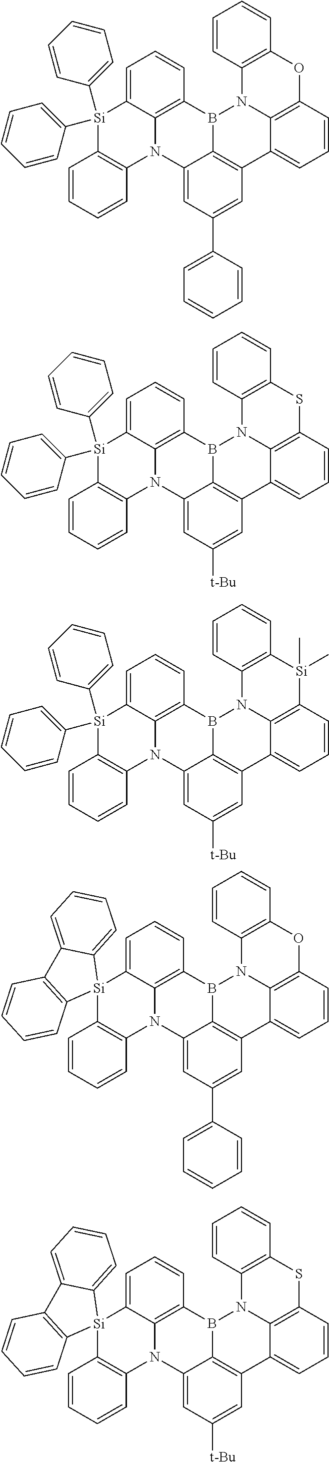 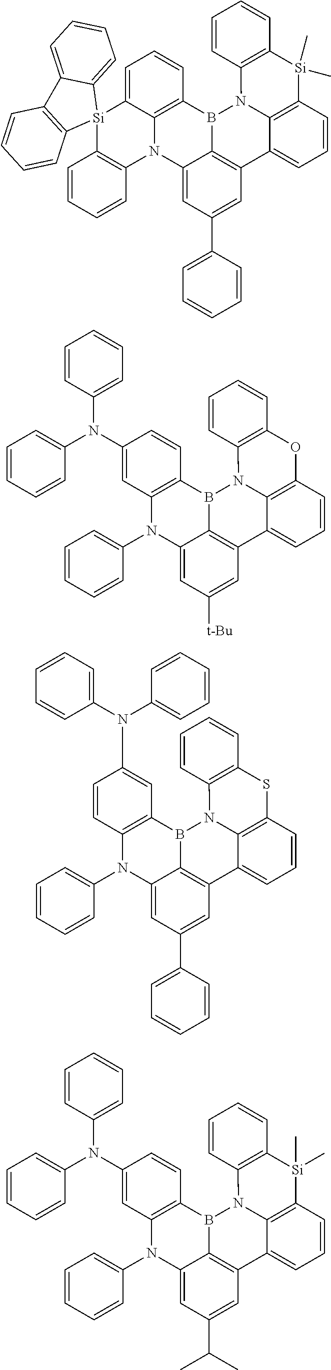 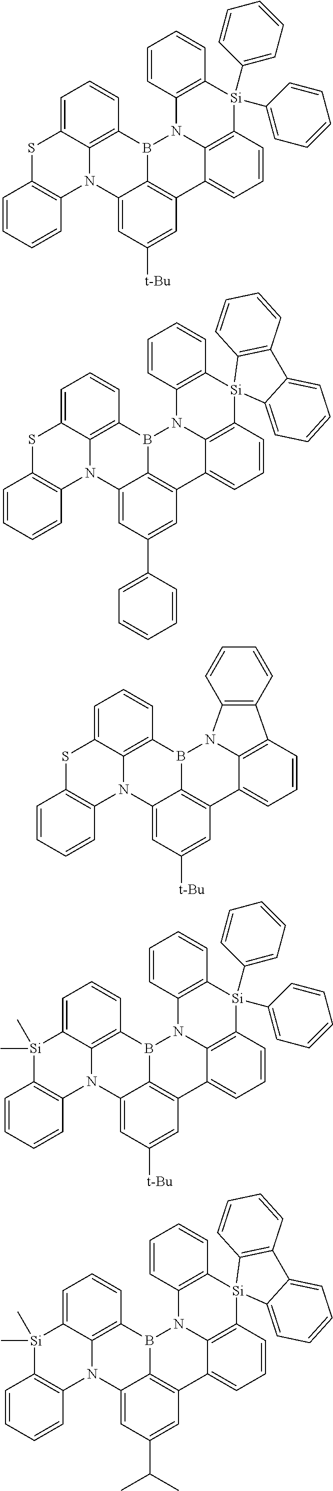 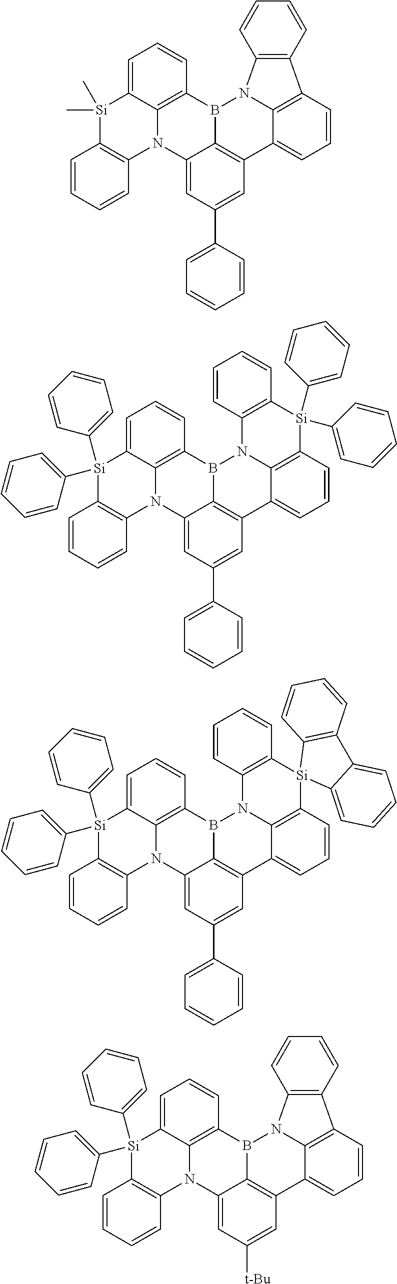 [SMILES: C[Si]1(C)c2ccccc2N2c3cc(-c4ccccc4)cc4c3B(c3cccc1c32)n1c2ccccc2c2cccc-4c21 ; c1ccc(-c2cc3c4c(c2)N2c5ccccc5[Si](c5ccccc5)(c5ccccc5)c5cccc(c52)B4N2c4ccccc4[Si](c4ccccc4)(c4ccccc4)c4cccc-3c42)cc1 ; c1ccc(-c2cc3c4c(c2)N2c5ccccc5[Si](c5ccccc5)(c5ccccc5)c5cccc(c52)B4N2c4ccccc4[Si]4(c5ccccc5-c5ccccc54)c4cccc-3c42)cc1 ; CC(C)(C)c1cc2c3c(c1)N1c4ccccc4[Si](c4ccccc4)(c4ccccc4)c4cccc(c41)B3n1c3ccccc3c3cccc-2c31] 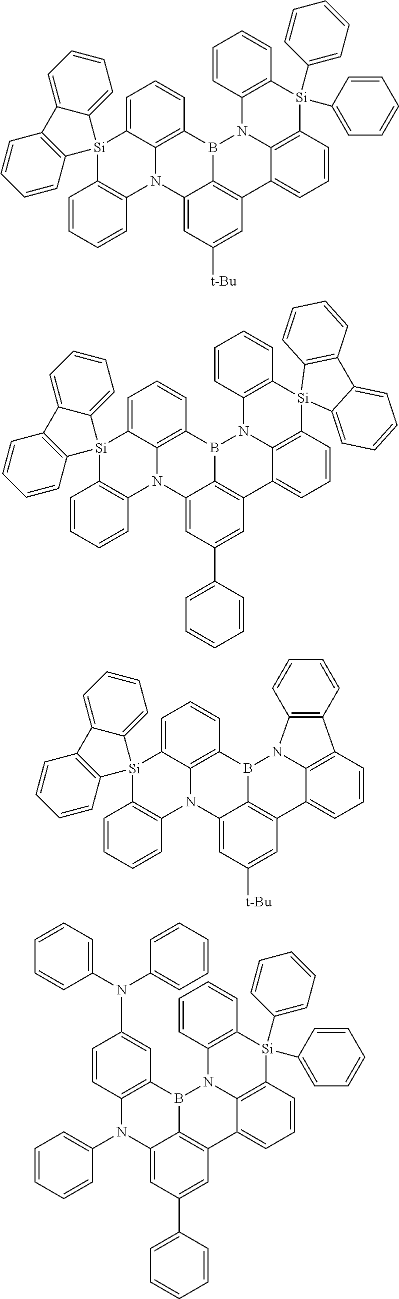 [SMILES: CC(C)(C)c1cc2c3c(c1)N1c4ccccc4[Si]4(c5ccccc5-c5ccccc54)c4cccc(c41)B3N1c3ccccc3[Si](c3ccccc3)(c3ccccc3)c3cccc-2c31 ; c1ccc(-c2cc3c4c(c2)N2c5ccccc5[Si]5(c6ccccc6-c6ccccc65)c5cccc(c52)B4N2c4ccccc4[Si]4(c5ccccc5-c5ccccc54)c4cccc-3c42)cc1 ; CC(C)(C)c1cc2c3c(c1)N1c4ccccc4[Si]4(c5ccccc5-c5ccccc54)c4cccc(c41)B3n1c3ccccc3c3cccc-2c31 ; c1ccc(-c2cc3c4c(c2)N(c2ccccc2)c2ccc(N(c5ccccc5)c5ccccc5)cc2B4N2c4ccccc4[Si](c4ccccc4)(c4ccccc4)c4cccc-3c42)cc1] 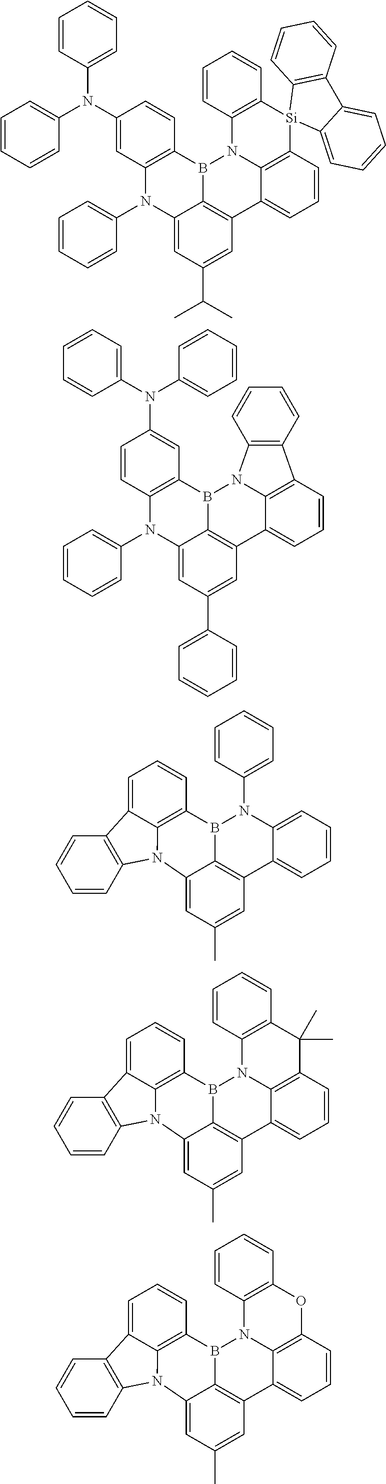 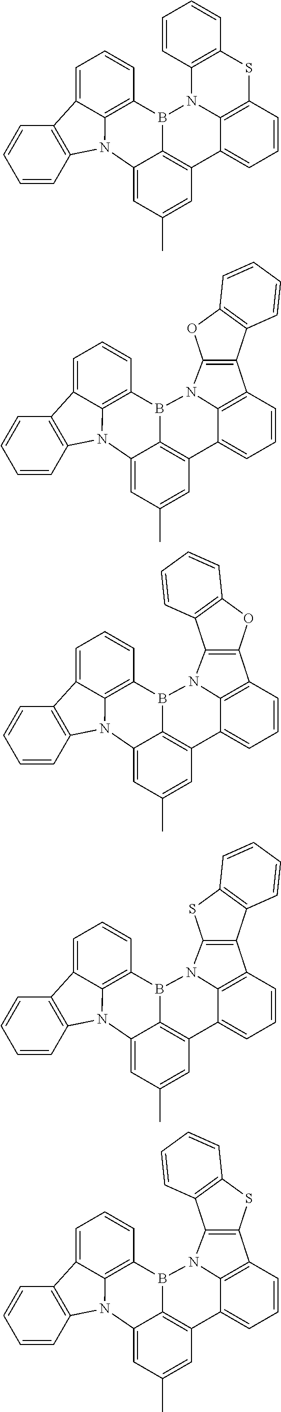 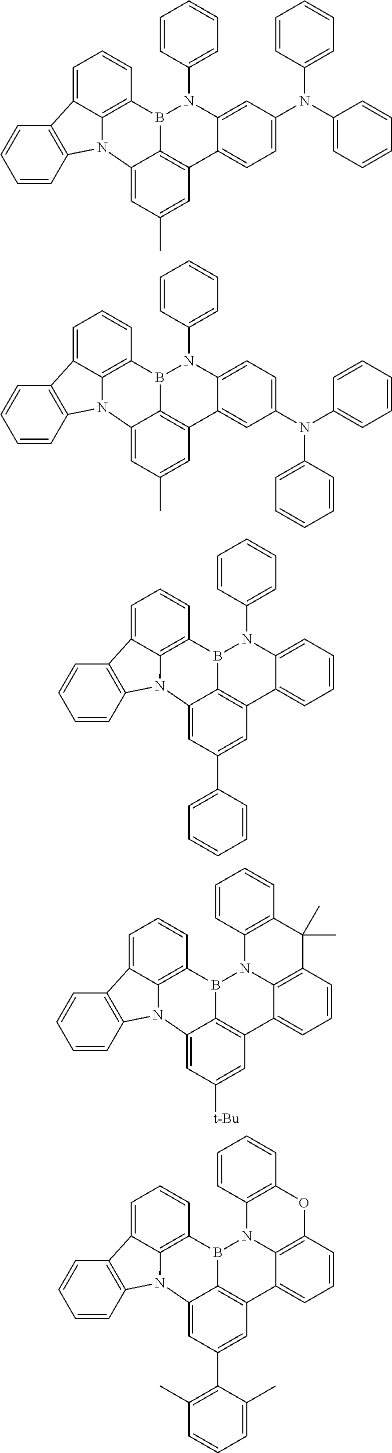 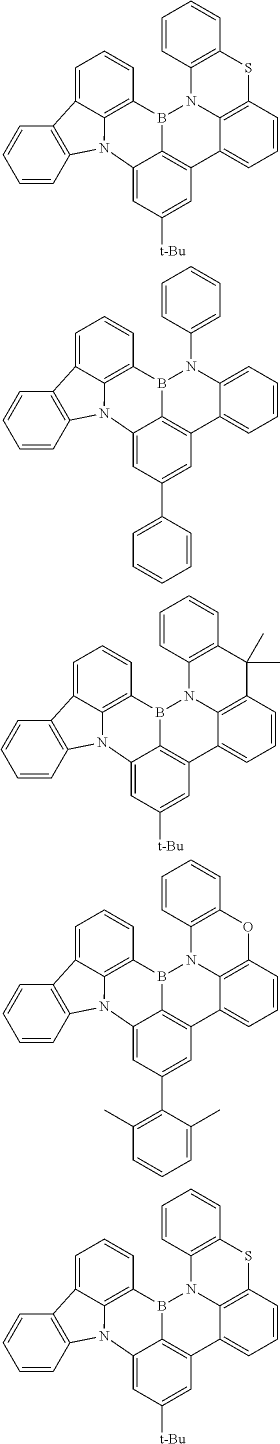 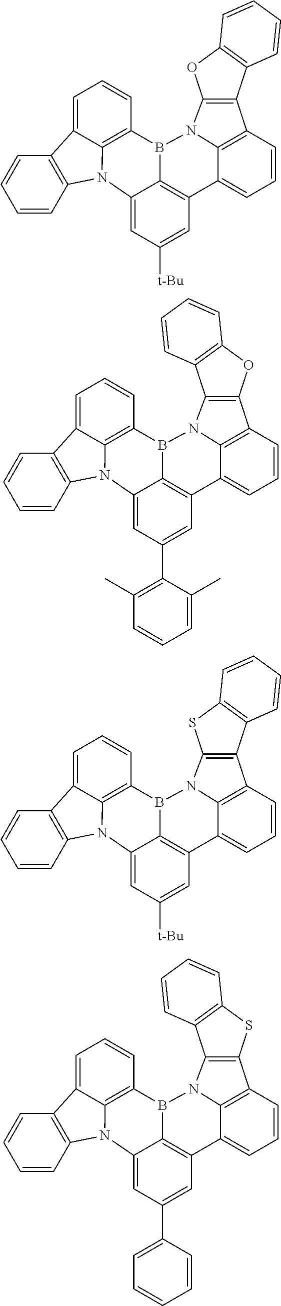 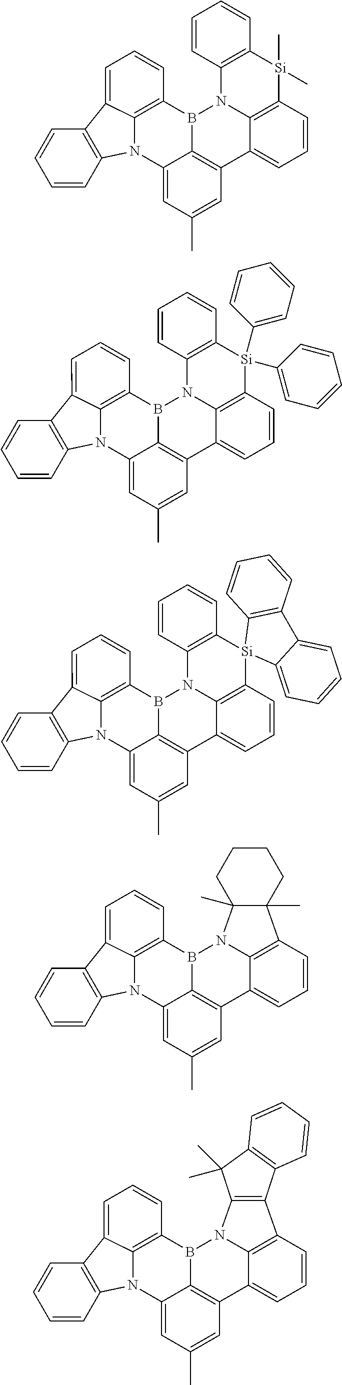 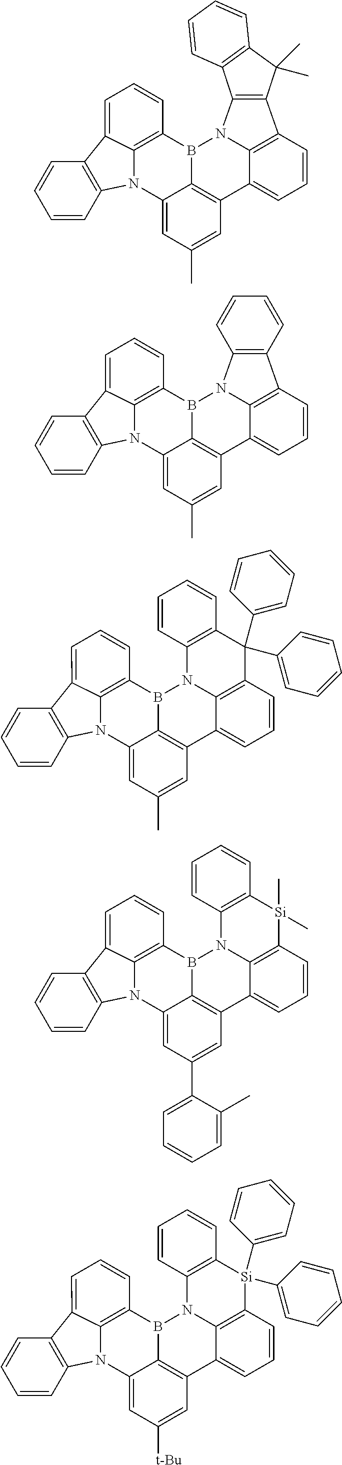 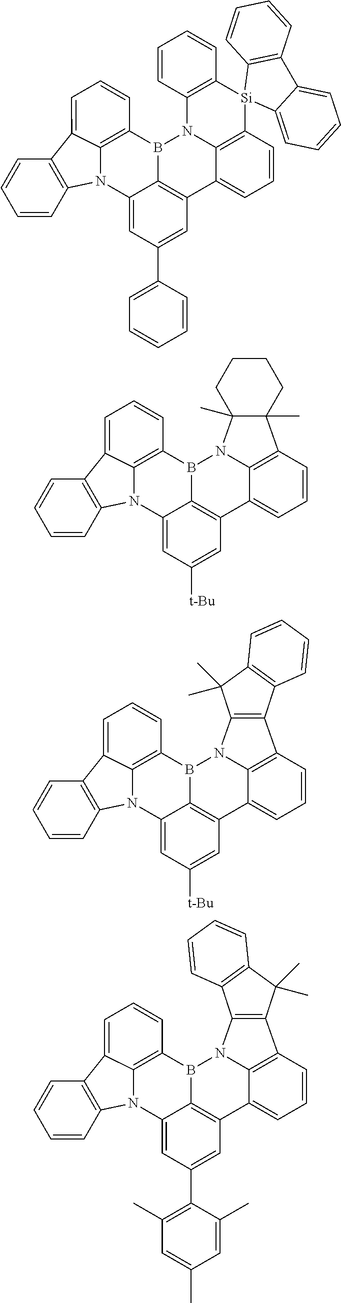 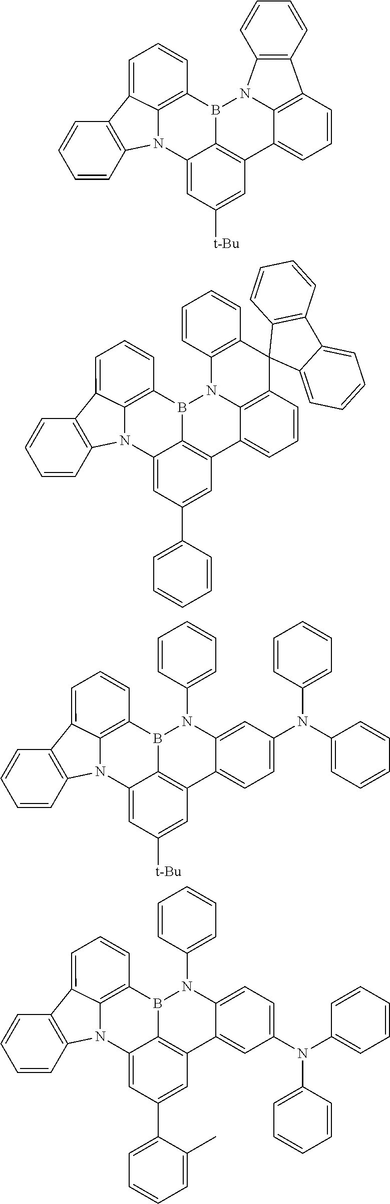 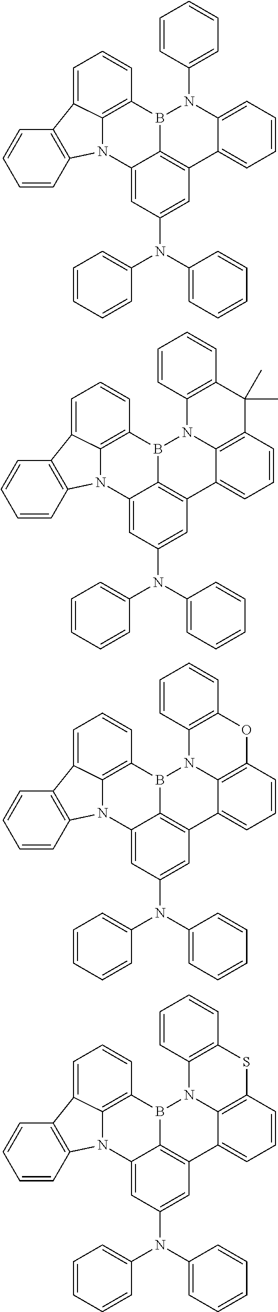 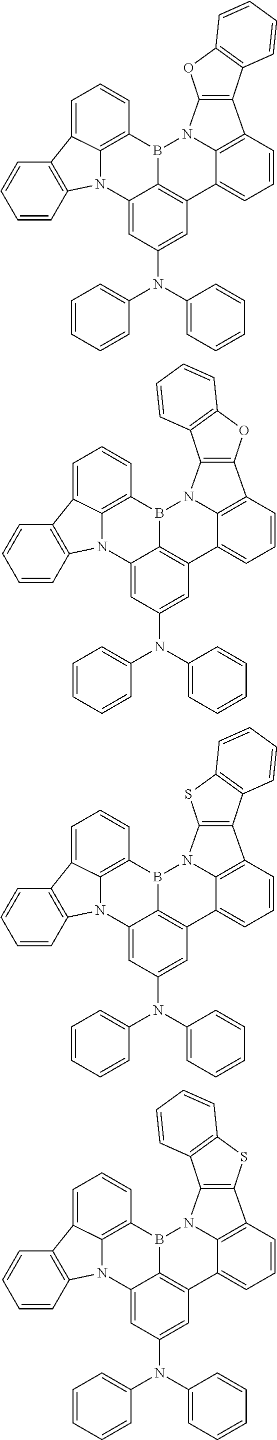 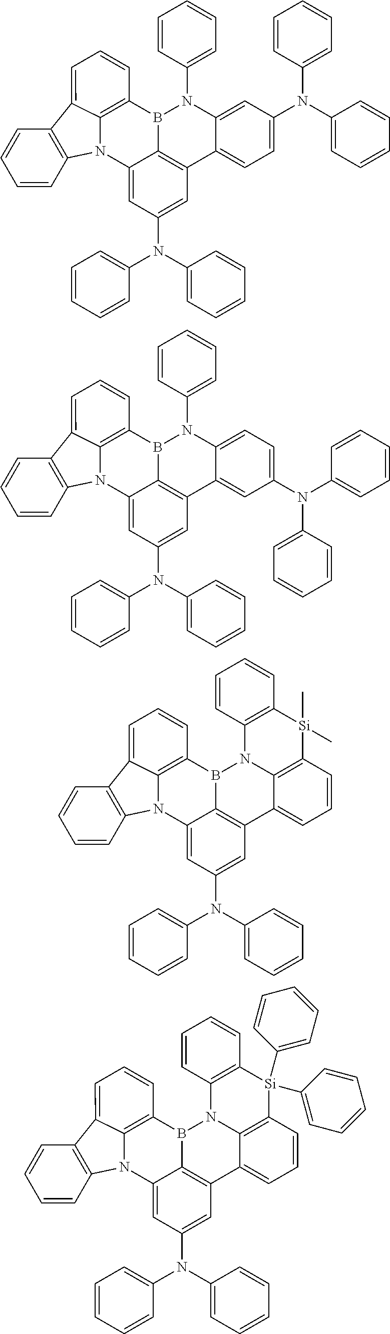 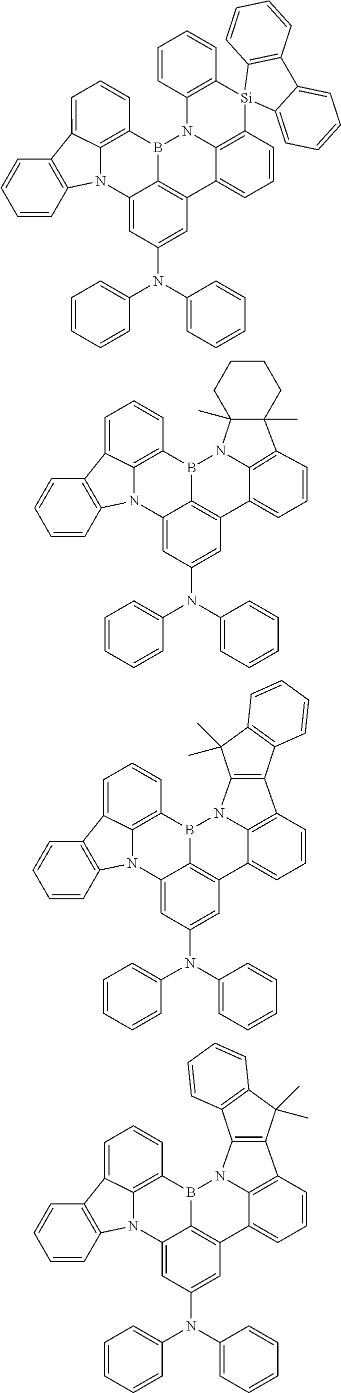 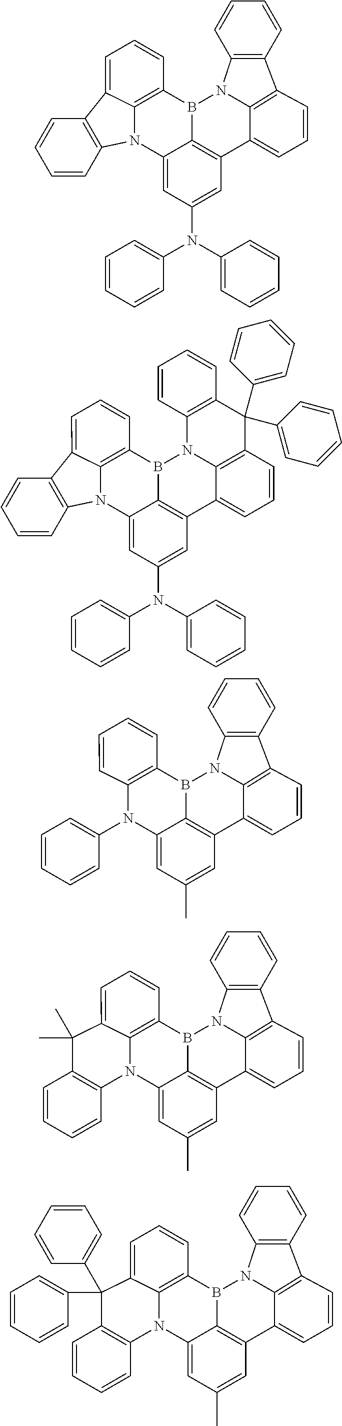 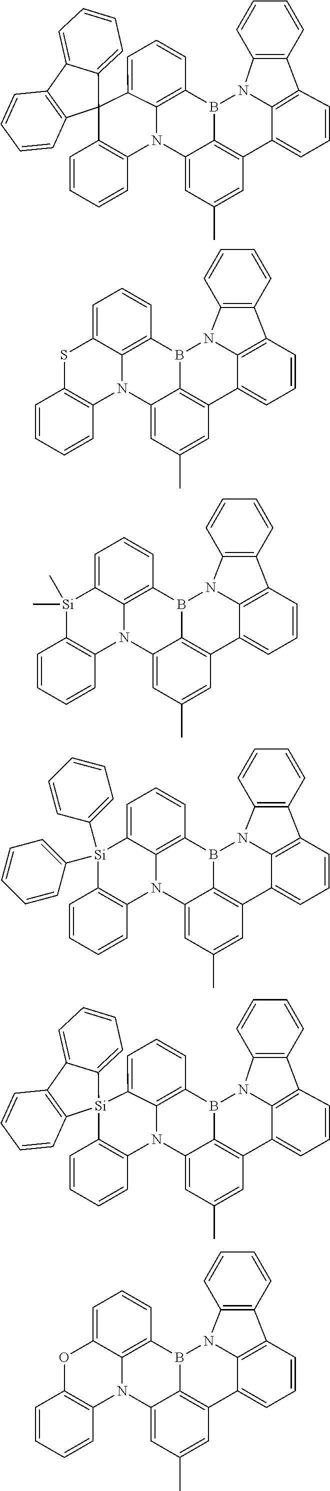 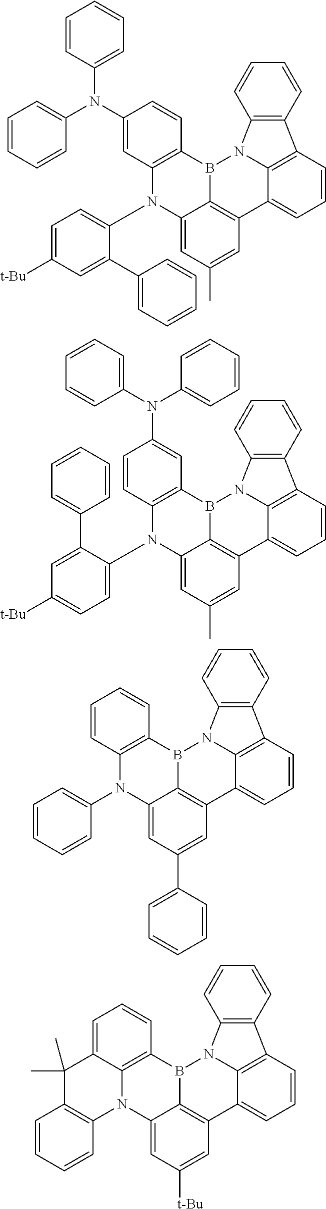 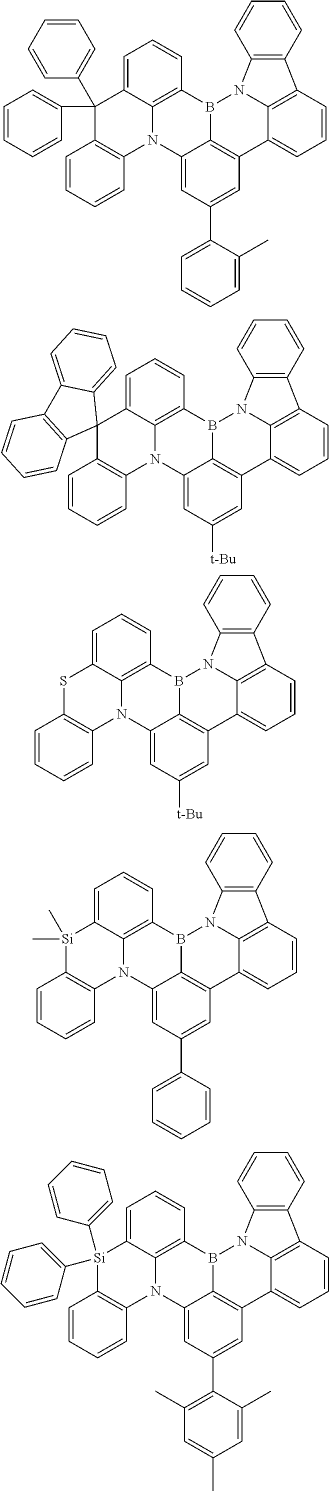 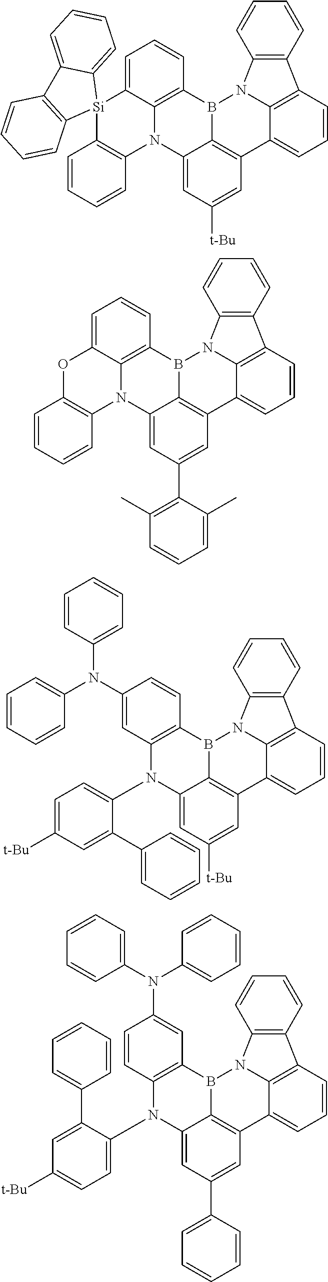 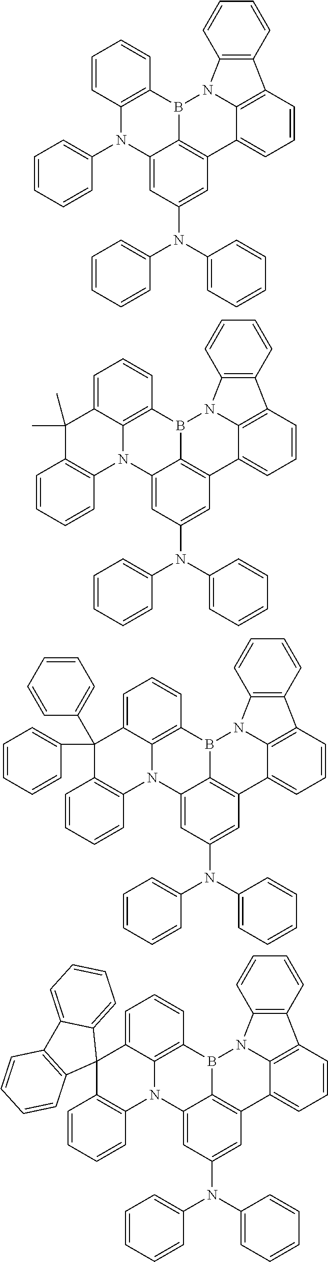 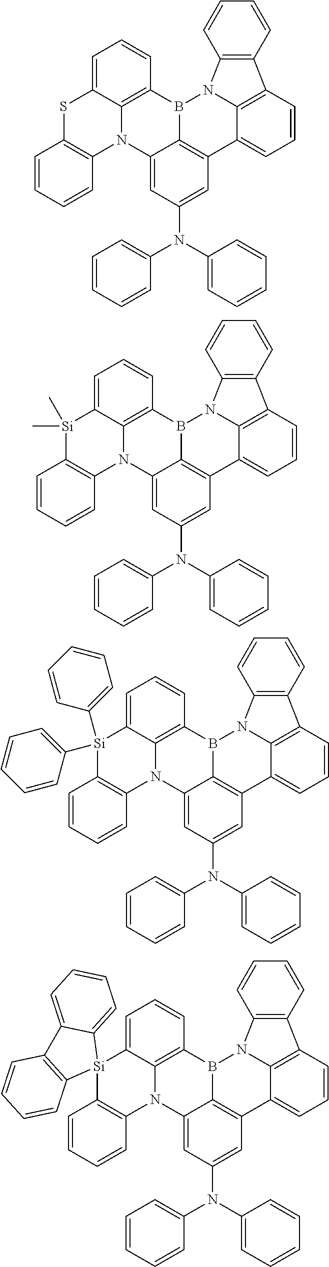 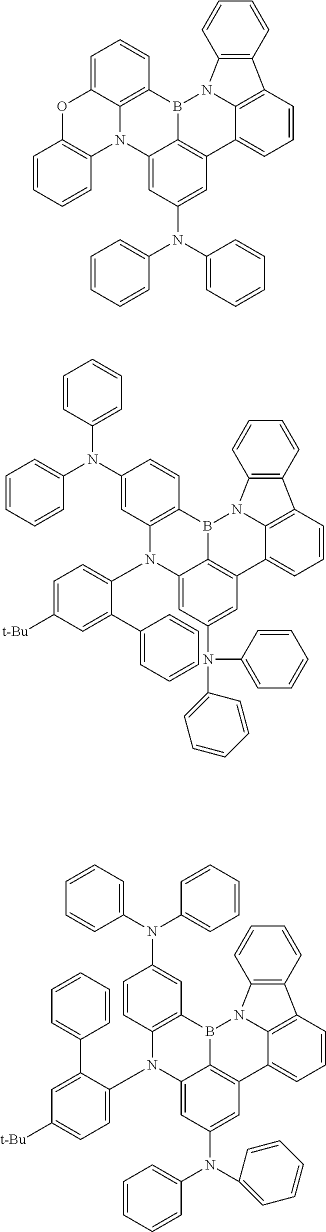 [SMILES: c1ccc(N(c2ccccc2)c2cc3c4c(c2)N2c5ccccc5Oc5cccc(c52)B4n2c4ccccc4c4cccc-3c42)cc1 ; CC(C)(C)c1ccc(N2c3cc(N(c4ccccc4)c4ccccc4)ccc3B3c4c(cc(N(c5ccccc5)c5ccccc5)cc42)-c2cccc4c5ccccc5n3c24)c(-c2ccccc2)c1 ; CC(C)(C)c1ccc(N2c3ccc(N(c4ccccc4)c4ccccc4)cc3B3c4c(cc(N(c5ccccc5)c5ccccc5)cc42)-c2cccc4c5ccccc5n3c24)c(-c2ccccc2)c1] 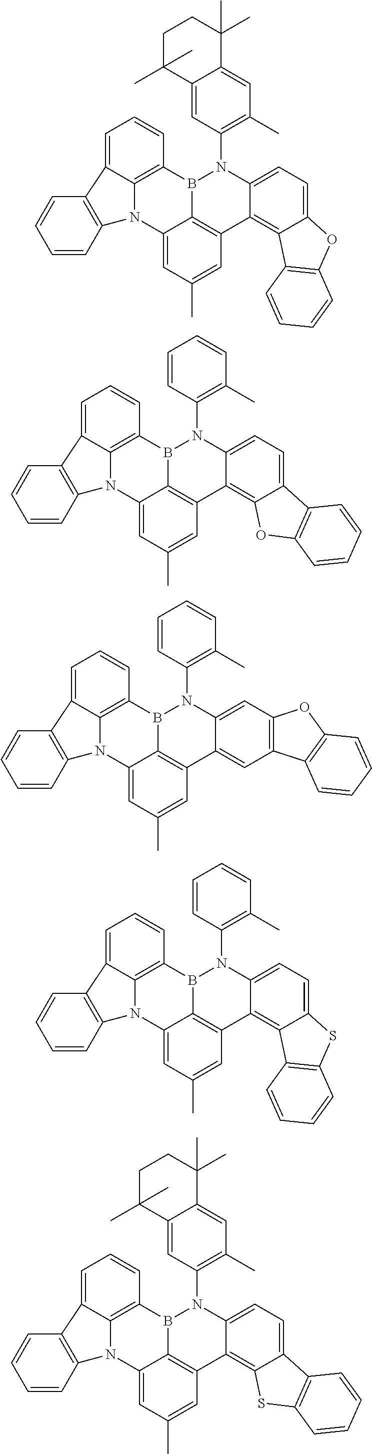 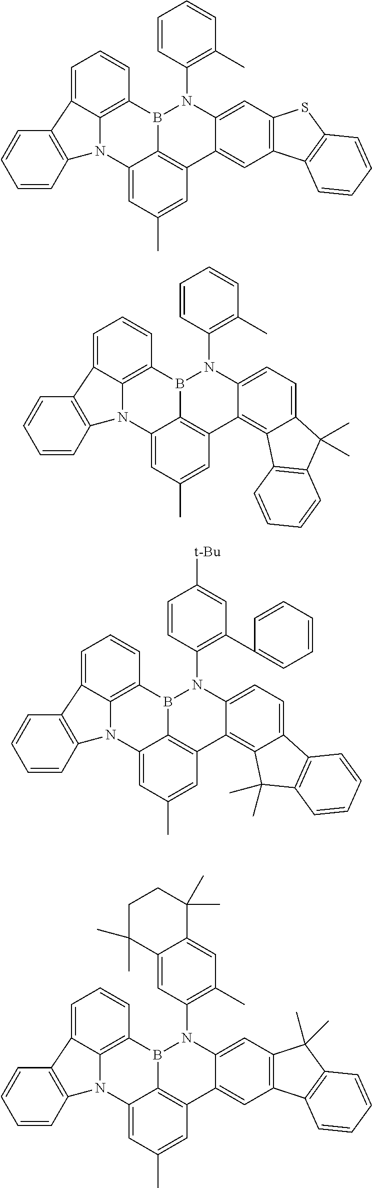 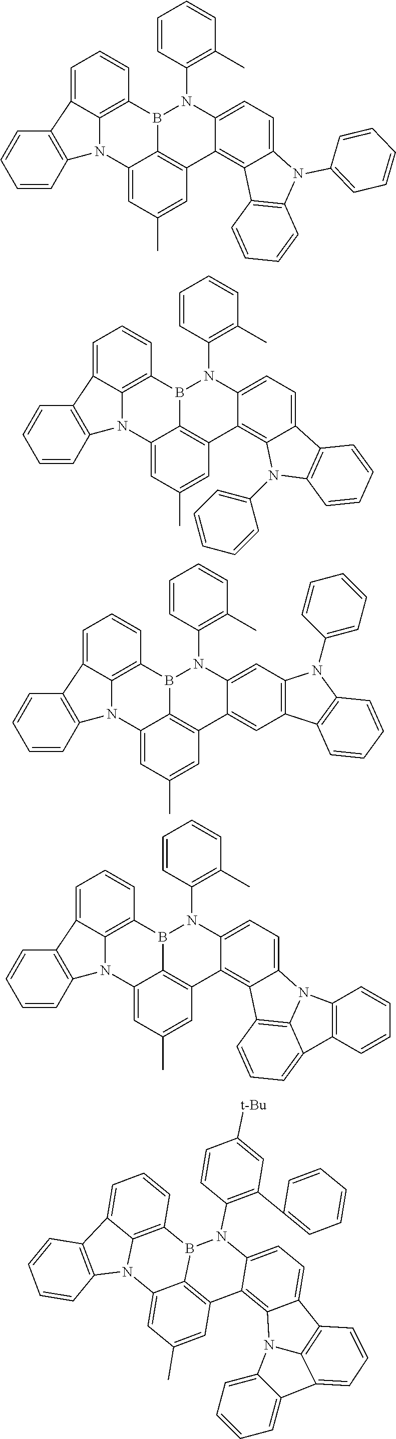 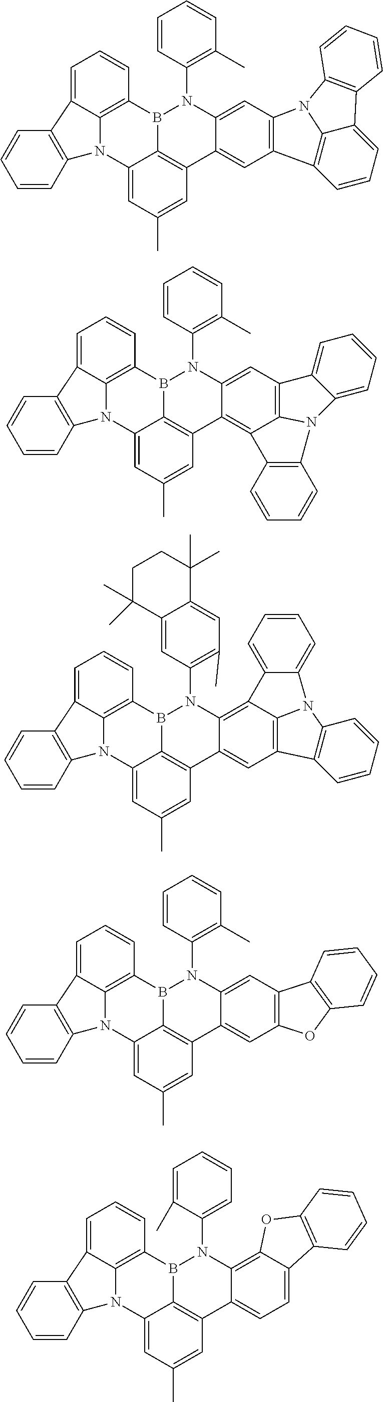 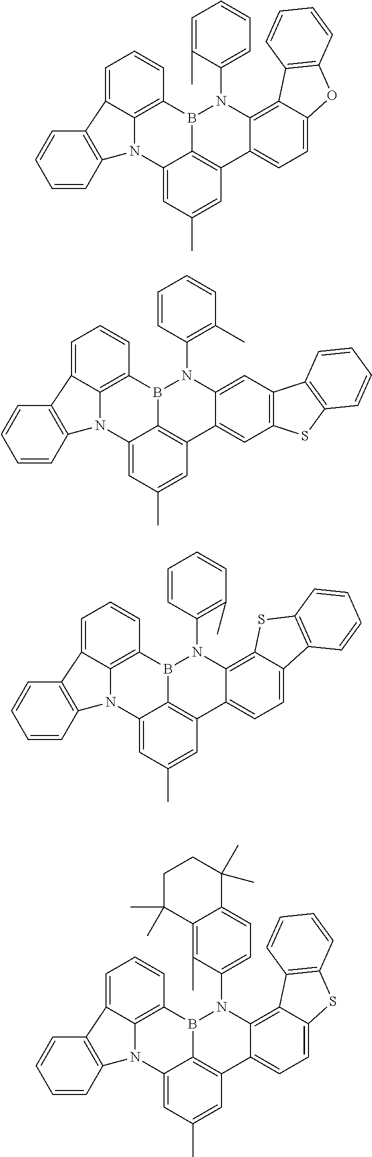 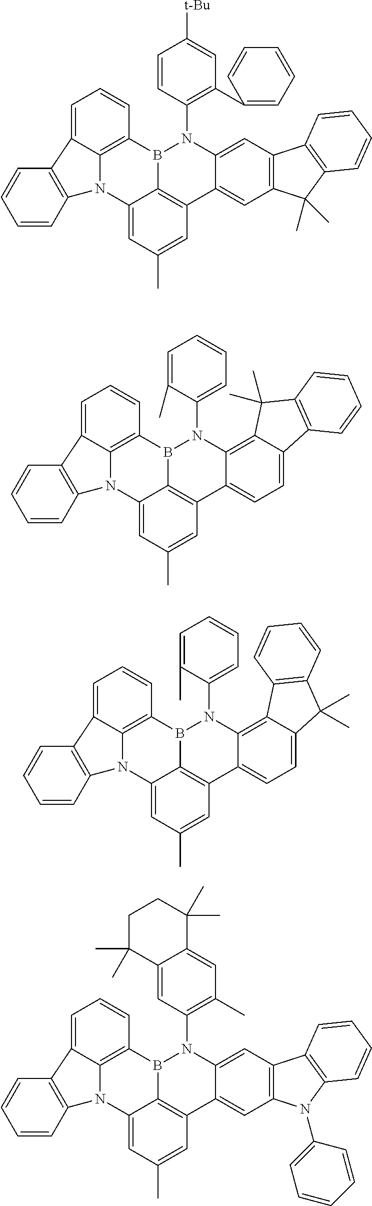 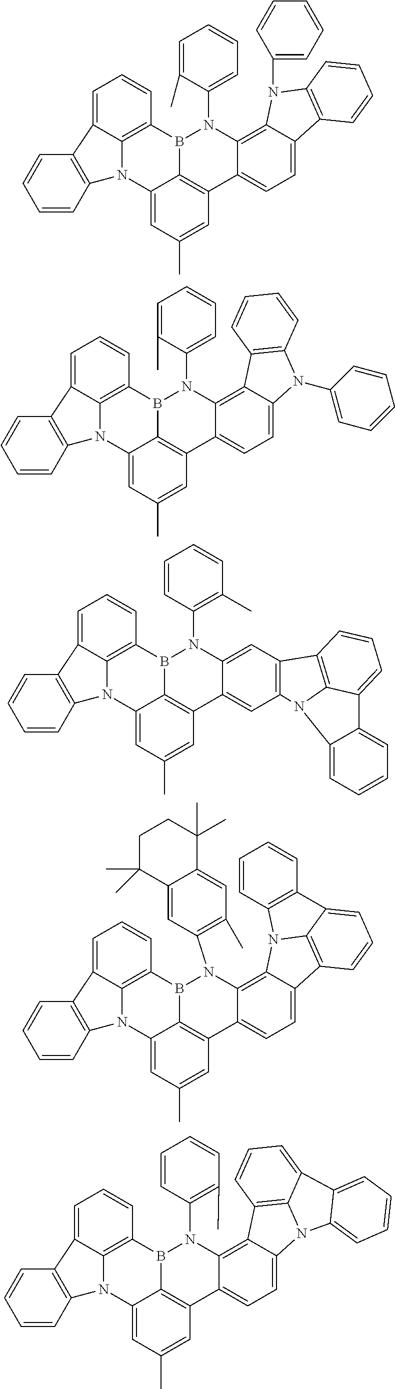 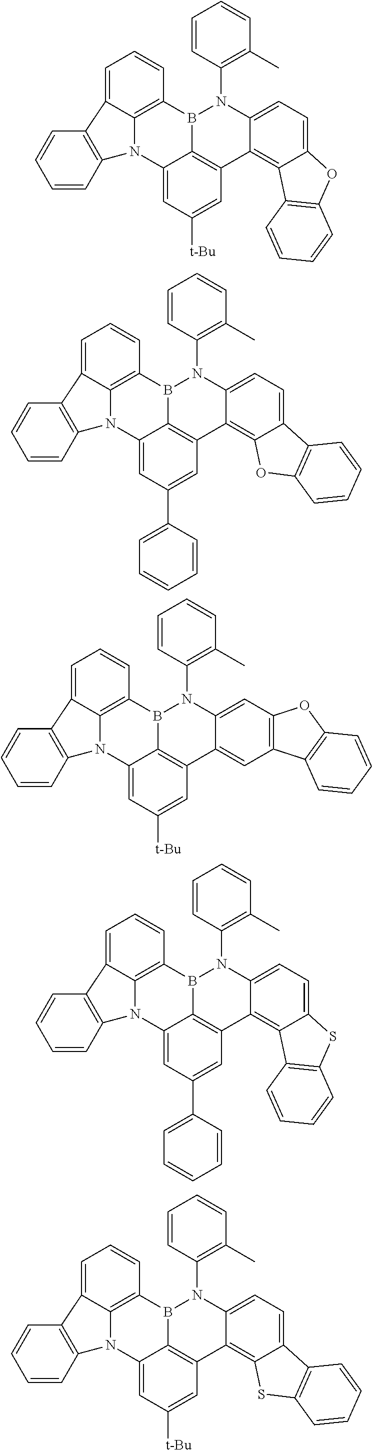 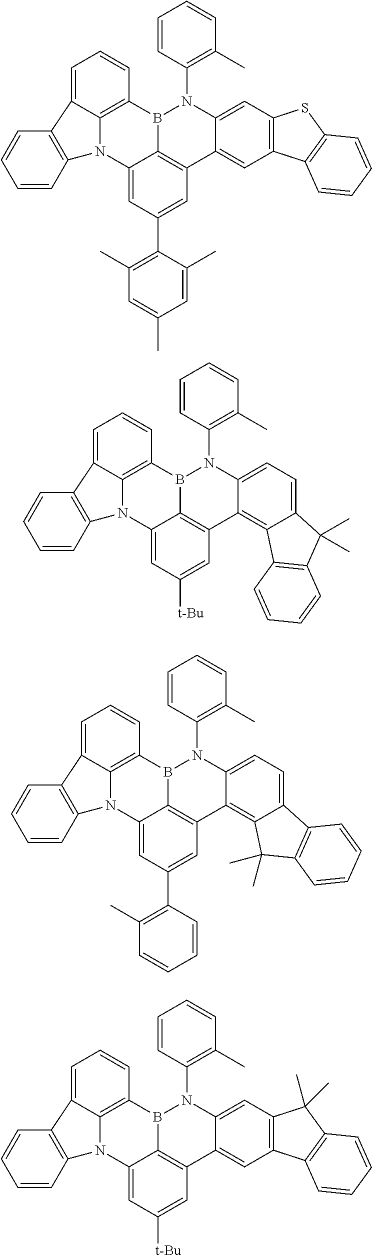 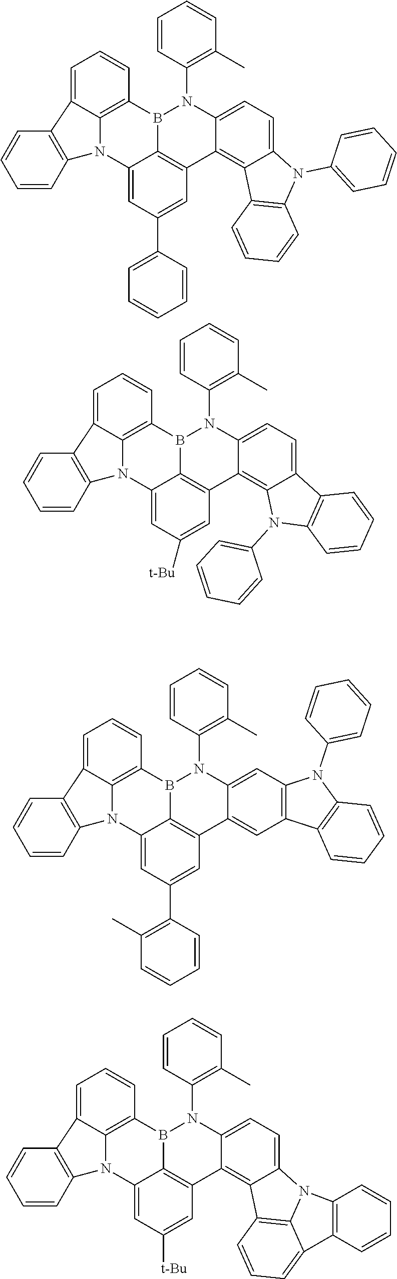 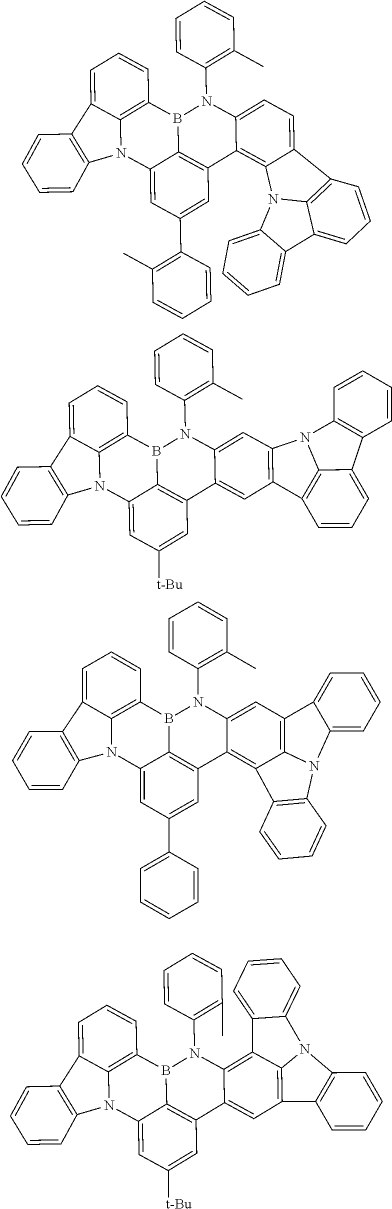 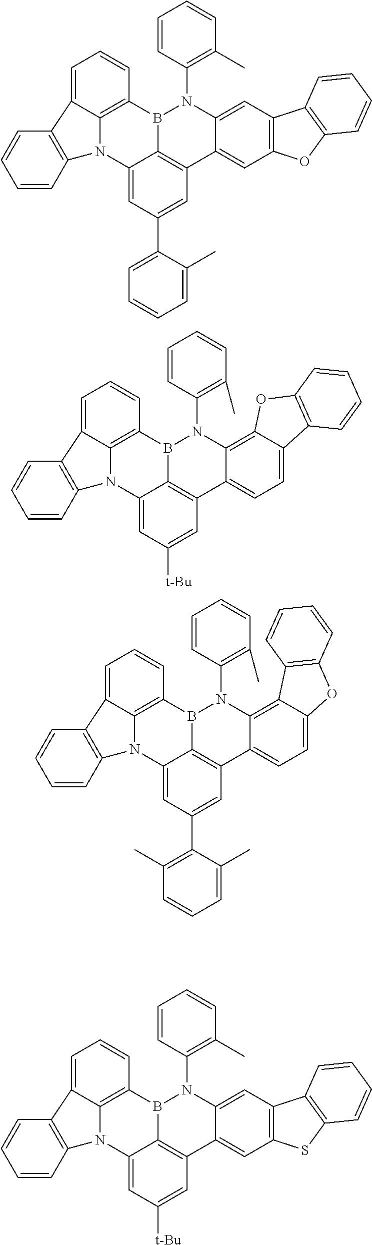 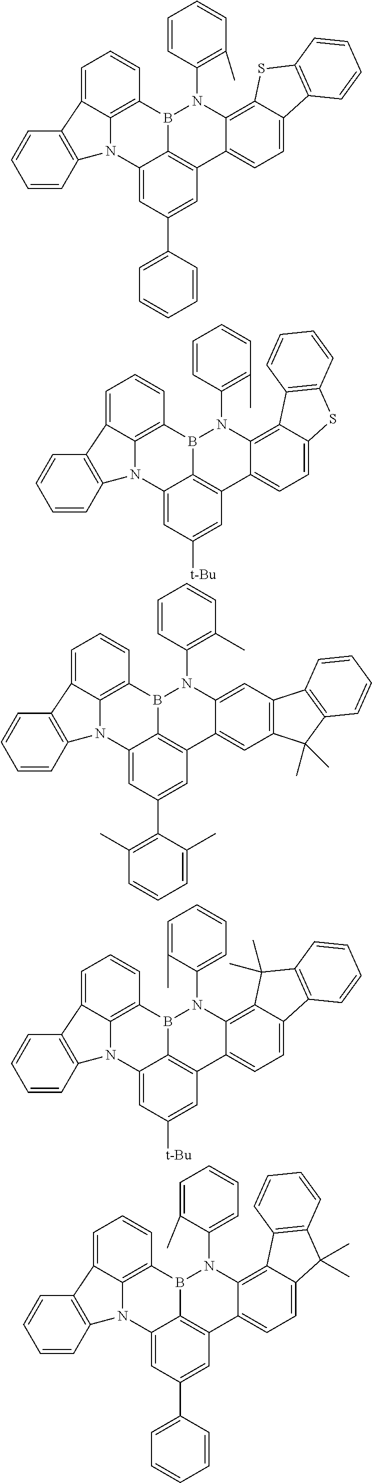 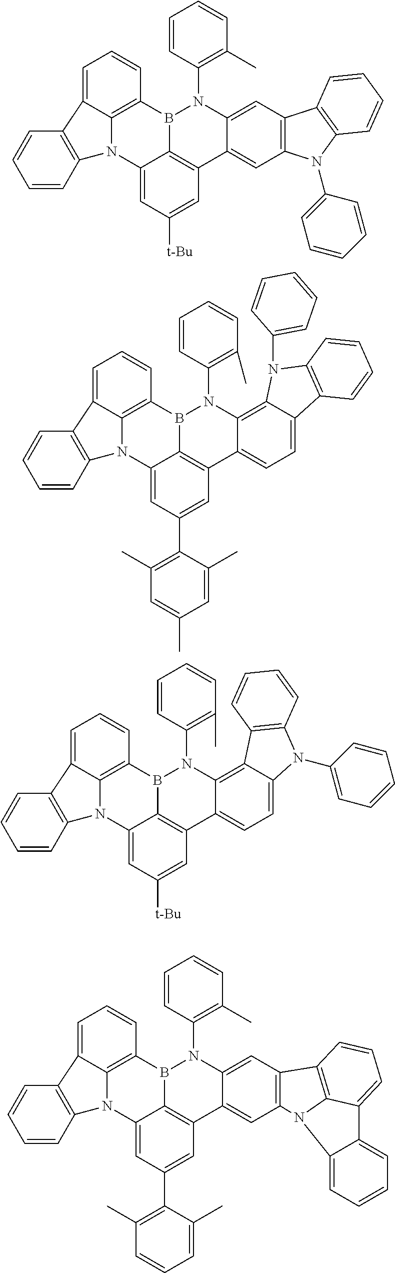 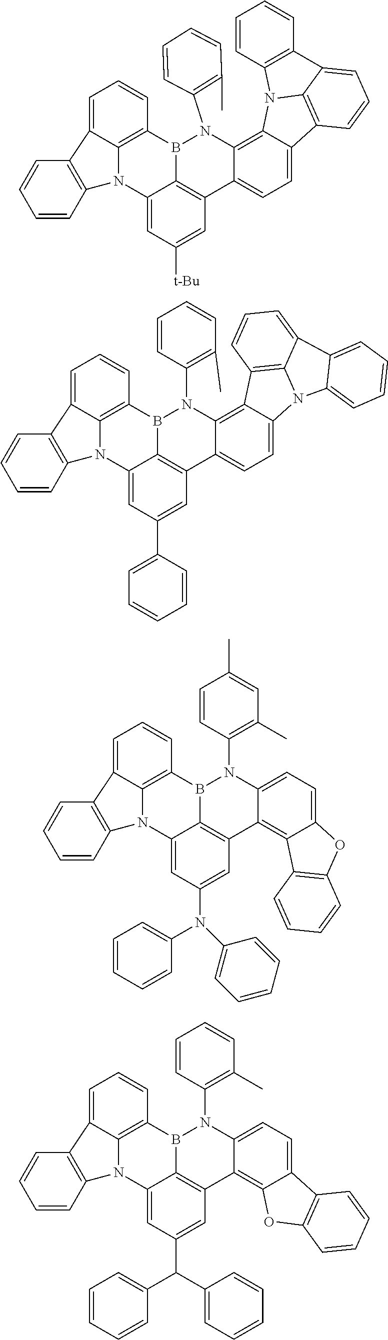 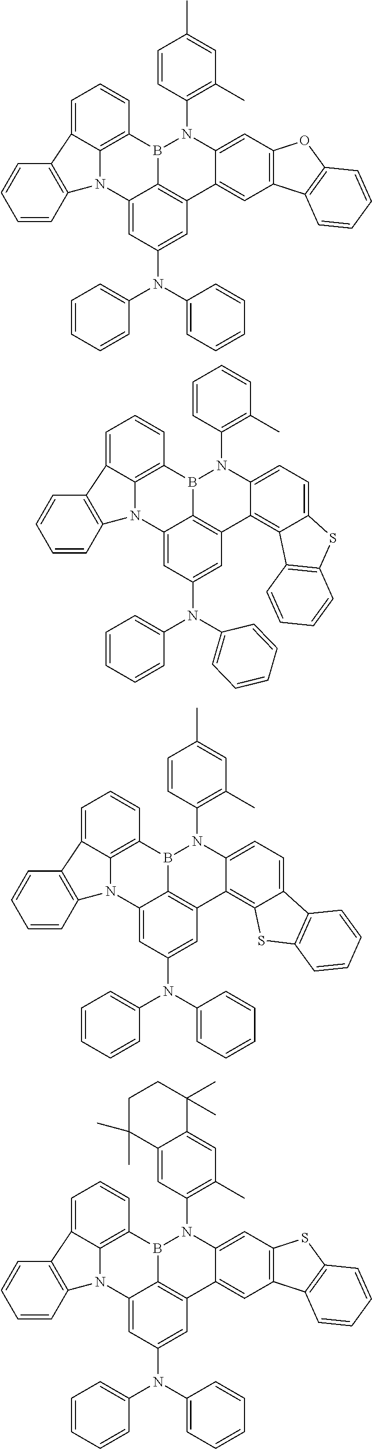 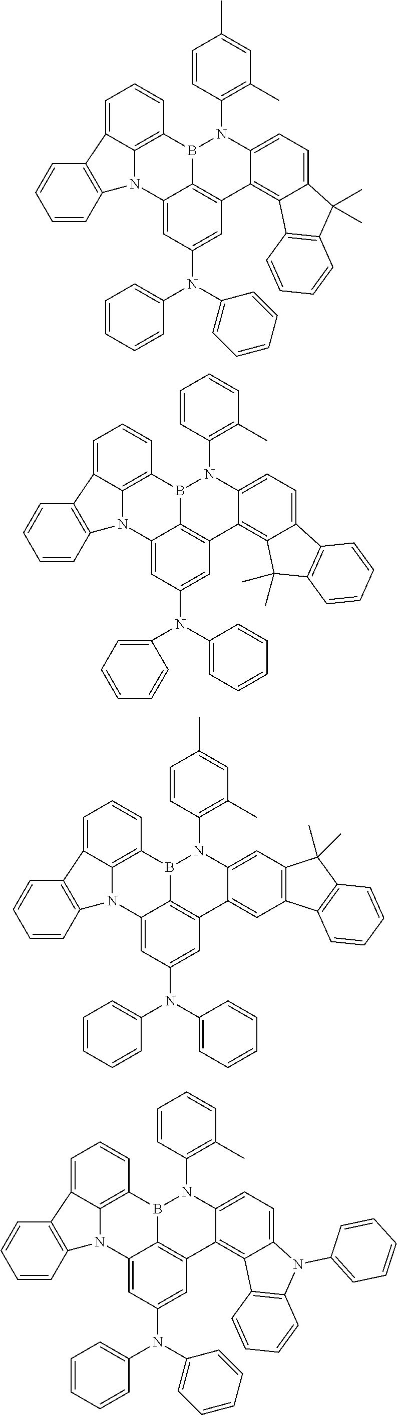 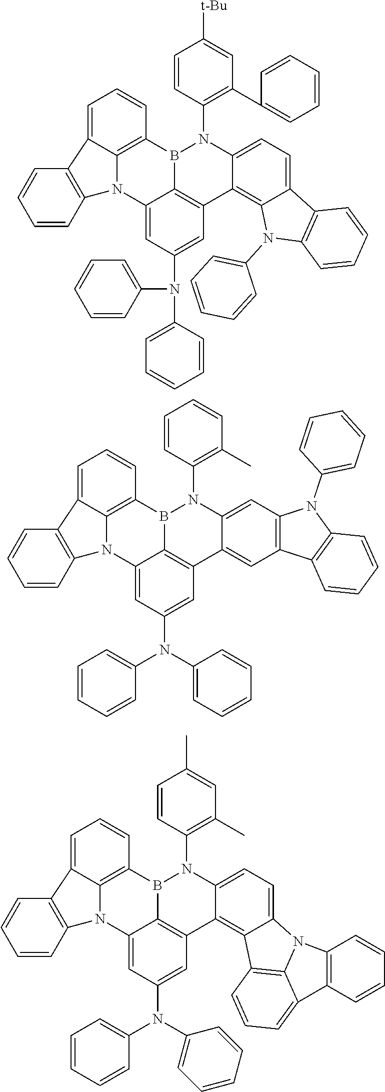 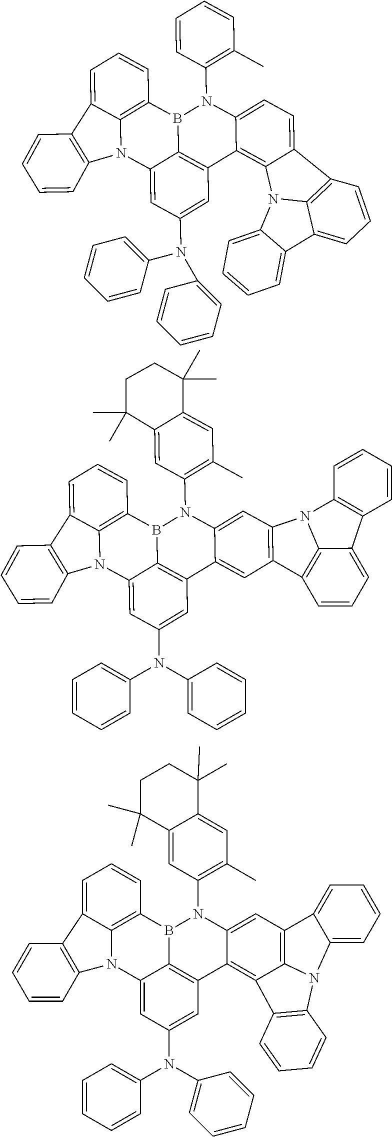 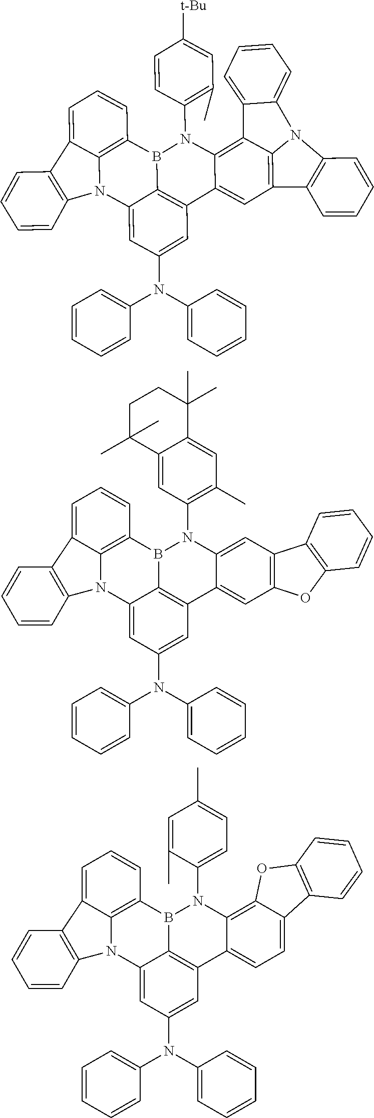 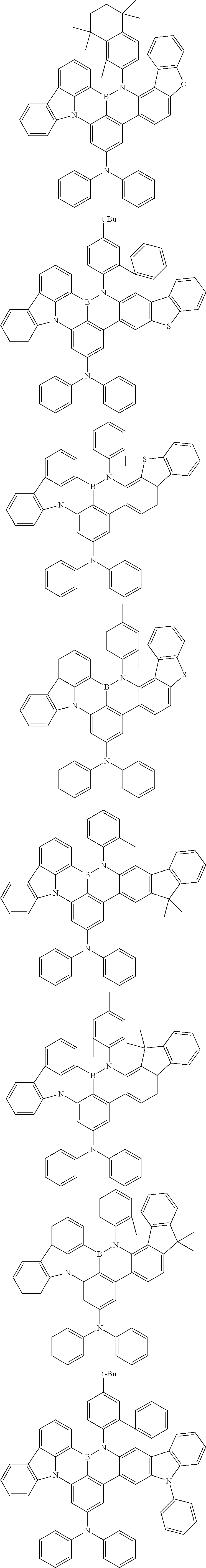 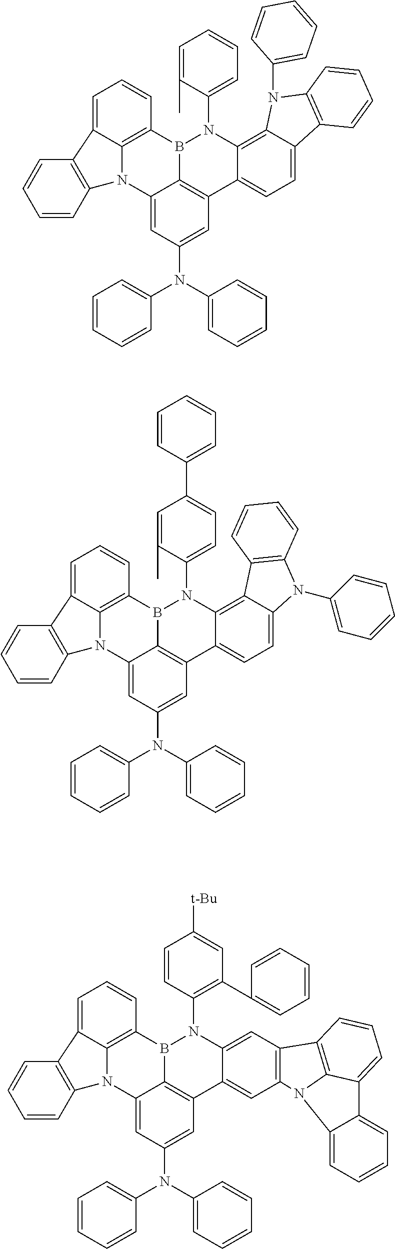 [SMILES: Cc1ccccc1N1B2c3c(cc(N(c4ccccc4)c4ccccc4)cc3-n3c4ccccc4c4cccc2c43)-c2ccc3c4ccccc4n(-c4ccccc4)c3c21 ; Cc1cc(-c2ccccc2)ccc1N1B2c3c(cc(N(c4ccccc4)c4ccccc4)cc3-n3c4ccccc4c4cccc2c43)-c2ccc3c(c21)c1ccccc1n3-c1ccccc1 ; CC(C)(C)c1ccc(N2B3c4c(cc(N(c5ccccc5)c5ccccc5)cc4-n4c5ccccc5c5cccc3c54)-c3cc4c(cc32)c2cccc3c5ccccc5n4c32)c(-c2ccccc2)c1] 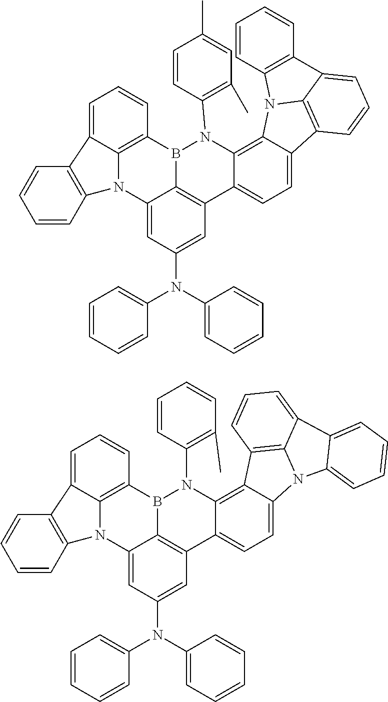 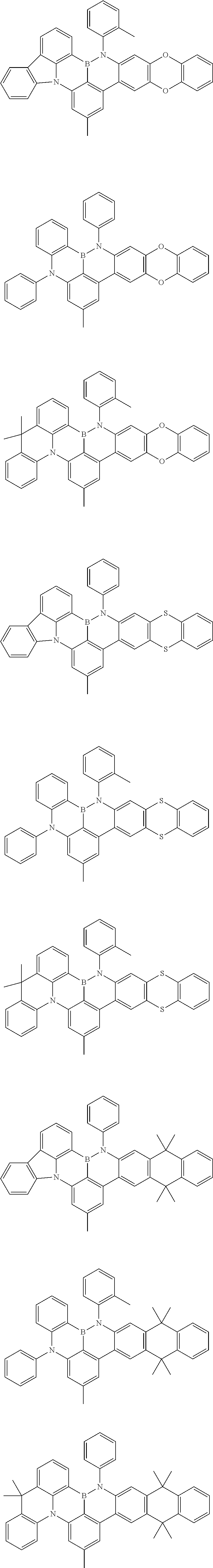 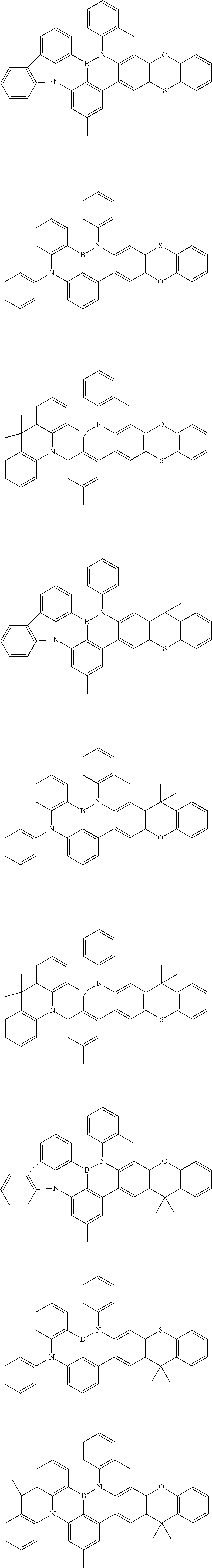 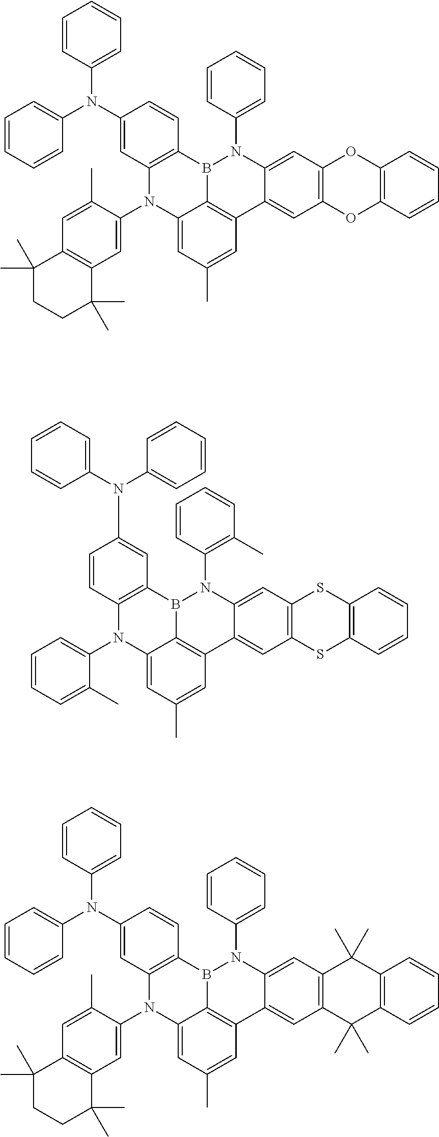 [SMILES: Cc1cc2c3c(c1)N(c1cc4c(cc1C)C(C)(C)CCC4(C)C)c1cc(N(c4ccccc4)c4ccccc4)ccc1B3N(c1ccccc1)c1cc3c(cc1-2)Oc1ccccc1O3 ; Cc1cc2c3c(c1)N(c1ccccc1C)c1ccc(N(c4ccccc4)c4ccccc4)cc1B3N(c1ccccc1C)c1cc3c(cc1-2)Sc1ccccc1S3 ; Cc1cc2c3c(c1)N(c1cc4c(cc1C)C(C)(C)CCC4(C)C)c1cc(N(c4ccccc4)c4ccccc4)ccc1B3N(c1ccccc1)c1cc3c(cc1-2)C(C)(C)c1ccccc1C3(C)C] 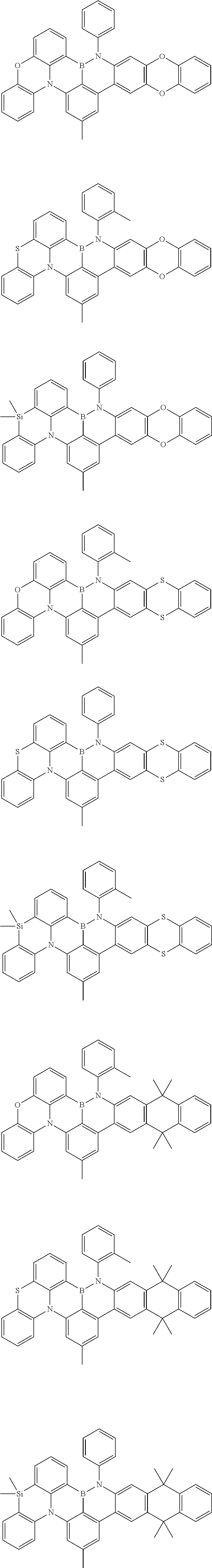 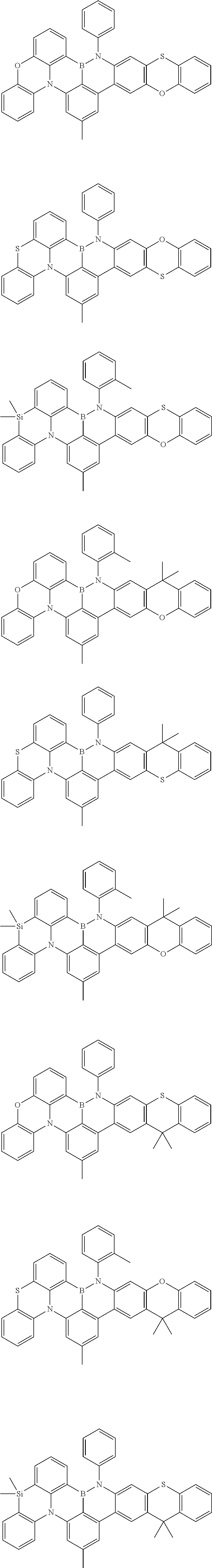 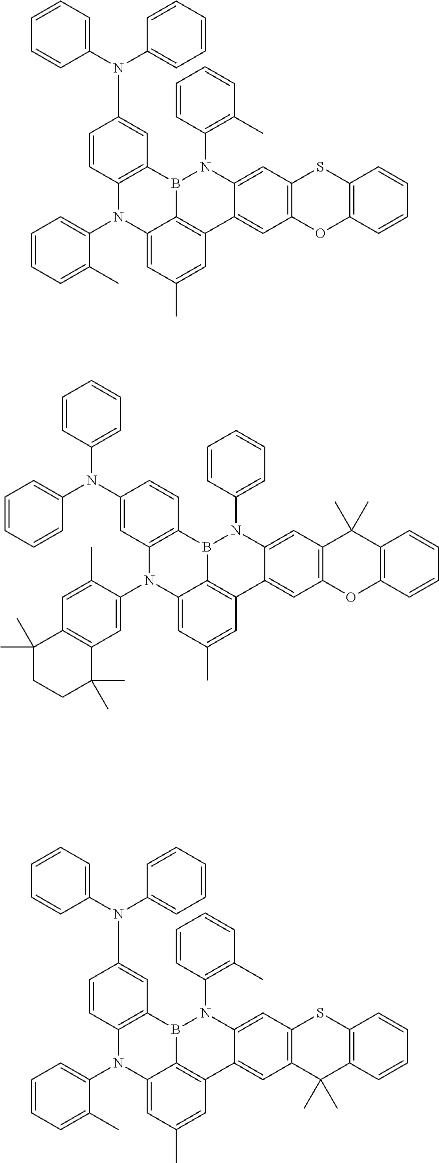 [SMILES: Cc1cc2c3c(c1)N(c1ccccc1C)c1ccc(N(c4ccccc4)c4ccccc4)cc1B3N(c1ccccc1C)c1cc3c(cc1-2)Oc1ccccc1S3 ; Cc1cc2c3c(c1)N(c1cc4c(cc1C)C(C)(C)CCC4(C)C)c1cc(N(c4ccccc4)c4ccccc4)ccc1B3N(c1ccccc1)c1cc3c(cc1-2)Oc1ccccc1C3(C)C ; Cc1cc2c3c(c1)N(c1ccccc1C)c1ccc(N(c4ccccc4)c4ccccc4)cc1B3N(c1ccccc1C)c1cc3c(cc1-2)C(C)(C)c1ccccc1S3] 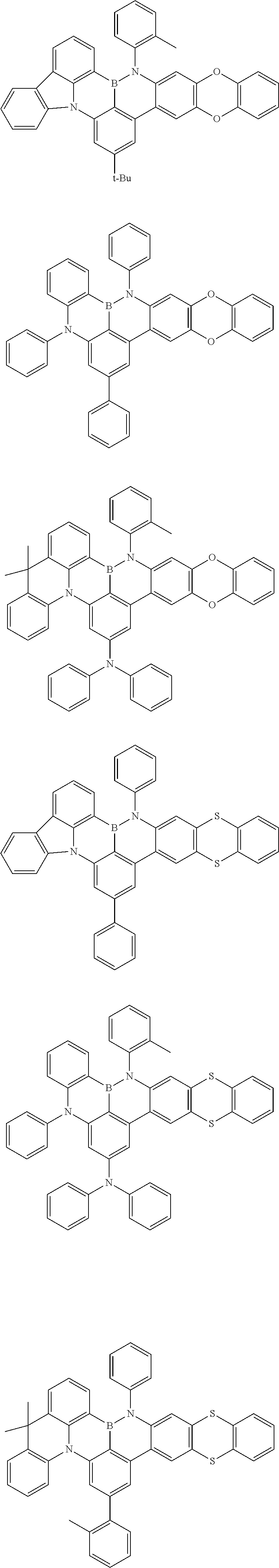 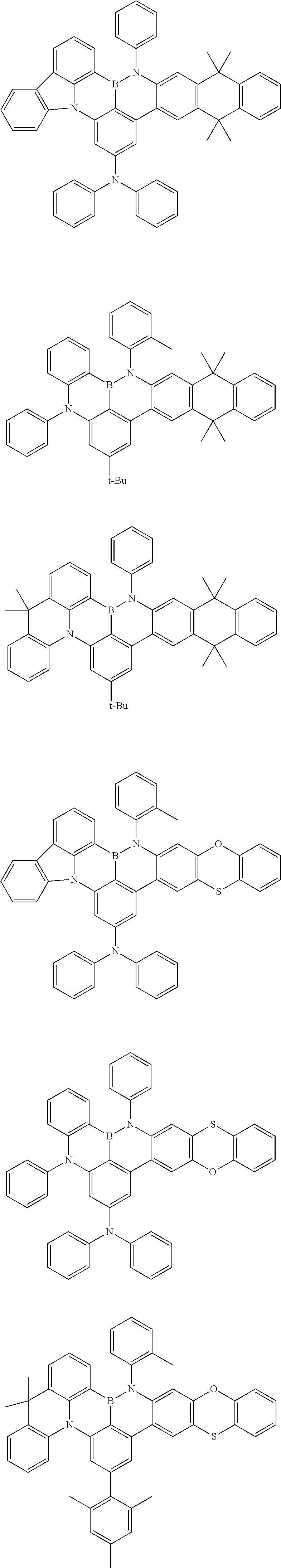 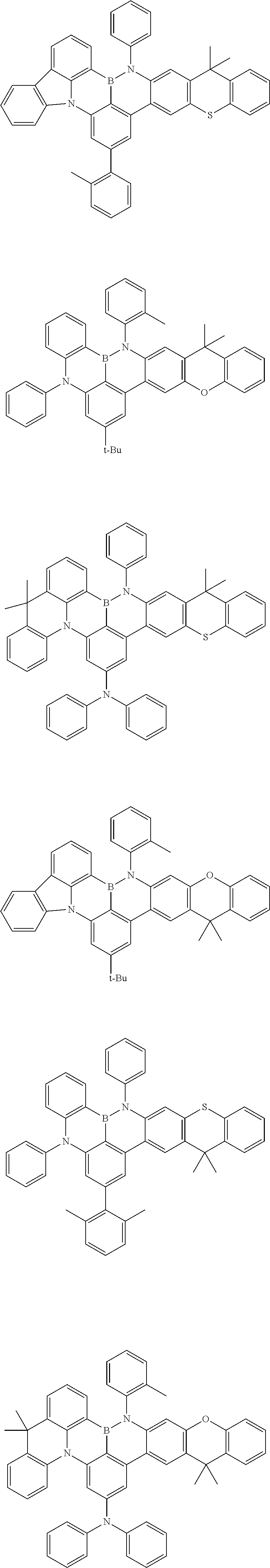 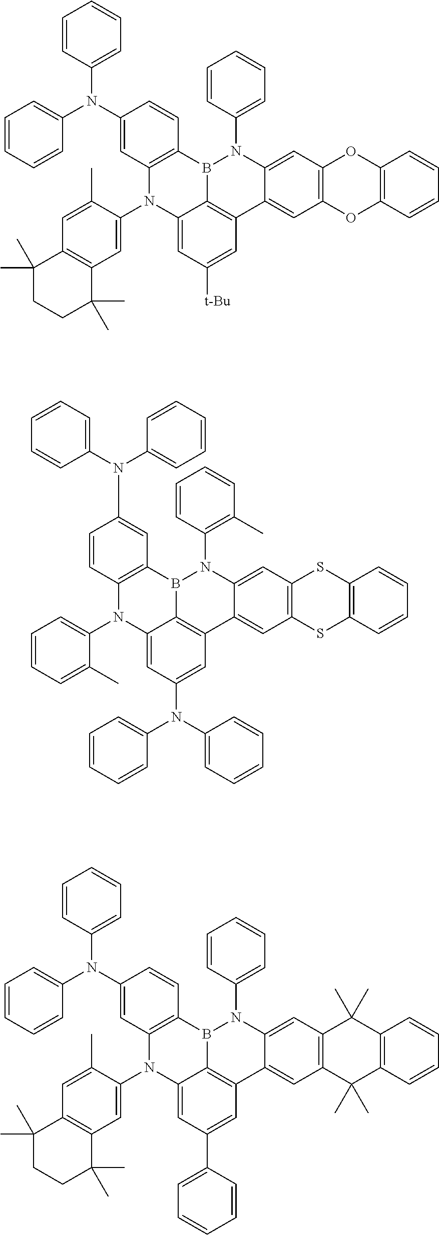 [SMILES: Cc1cc2c(cc1N1c3cc(N(c4ccccc4)c4ccccc4)ccc3B3c4c(cc(C(C)(C)C)cc41)-c1cc4c(cc1N3c1ccccc1)Oc1ccccc1O4)C(C)(C)CCC2(C)C ; Cc1ccccc1N1B2c3cc(N(c4ccccc4)c4ccccc4)ccc3N(c3ccccc3C)c3cc(N(c4ccccc4)c4ccccc4)cc(c32)-c2cc3c(cc21)Sc1ccccc1S3 ; Cc1cc2c(cc1N1c3cc(N(c4ccccc4)c4ccccc4)ccc3B3c4c(cc(-c5ccccc5)cc41)-c1cc4c(cc1N3c1ccccc1)C(C)(C)c1ccccc1C4(C)C)C(C)(C)CCC2(C)C] 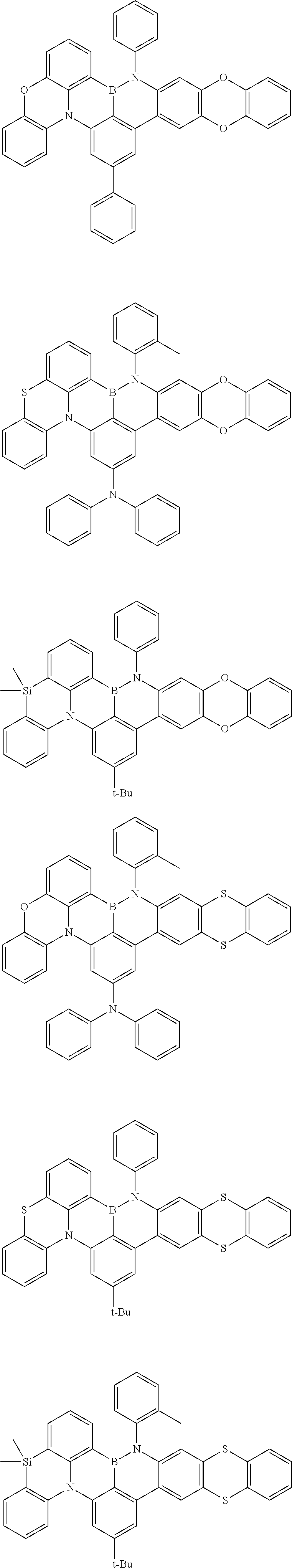 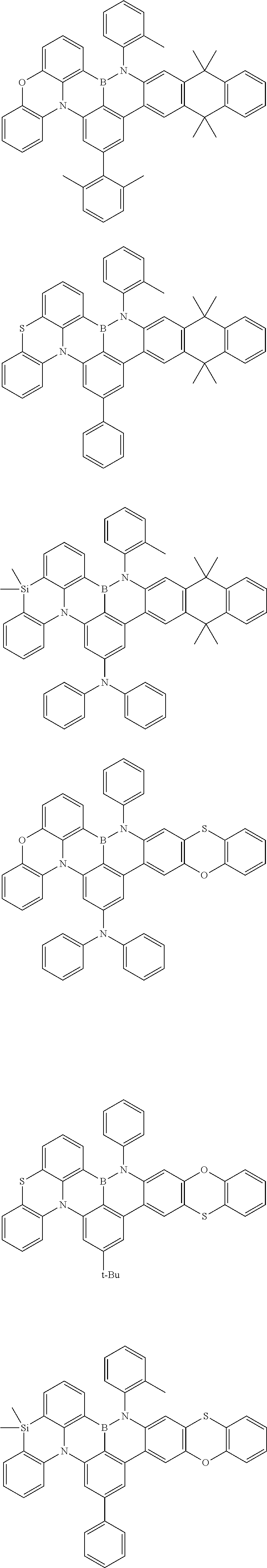 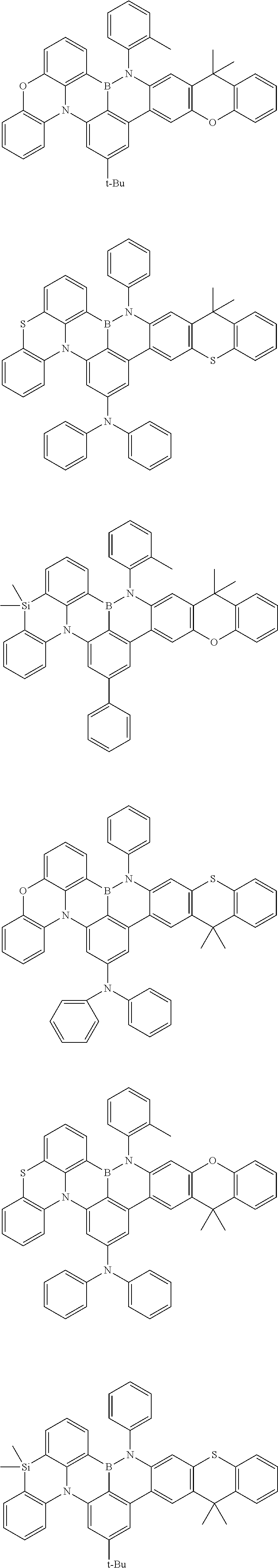 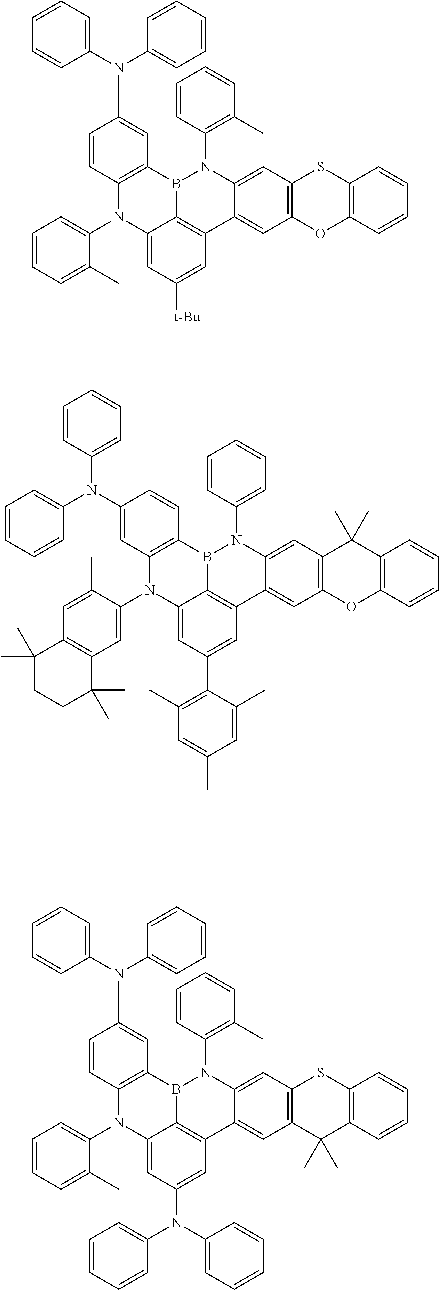 [SMILES: Cc1ccccc1N1B2c3cc(N(c4ccccc4)c4ccccc4)ccc3N(c3ccccc3C)c3cc(C(C)(C)C)cc(c32)-c2cc3c(cc21)Sc1ccccc1O3 ; Cc1cc(C)c(-c2cc3c4c(c2)N(c2cc5c(cc2C)C(C)(C)CCC5(C)C)c2cc(N(c5ccccc5)c5ccccc5)ccc2B4N(c2ccccc2)c2cc4c(cc2-3)Oc2ccccc2C4(C)C)c(C)c1 ; Cc1ccccc1N1B2c3cc(N(c4ccccc4)c4ccccc4)ccc3N(c3ccccc3C)c3cc(N(c4ccccc4)c4ccccc4)cc(c32)-c2cc3c(cc21)Sc1ccccc1C3(C)C] 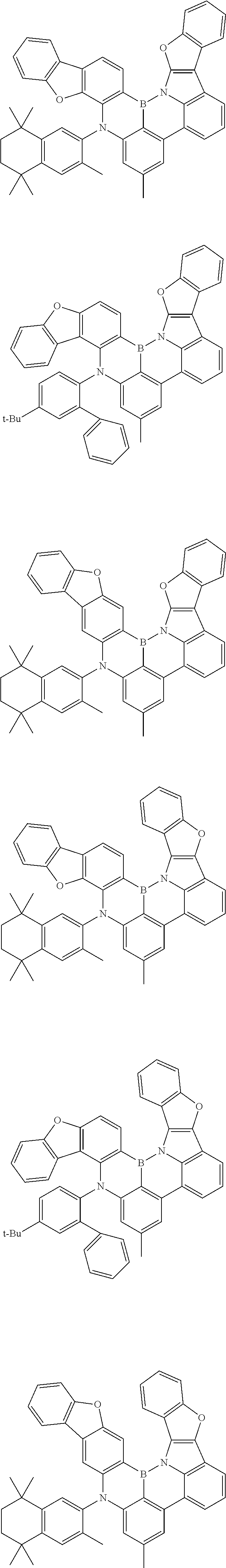 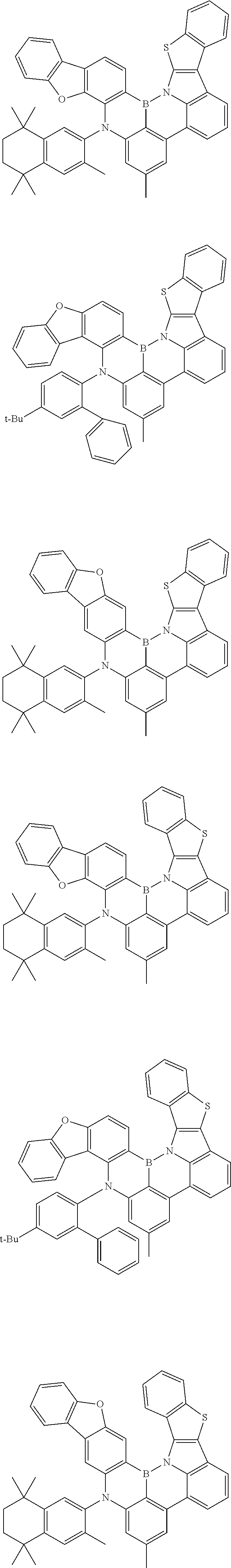 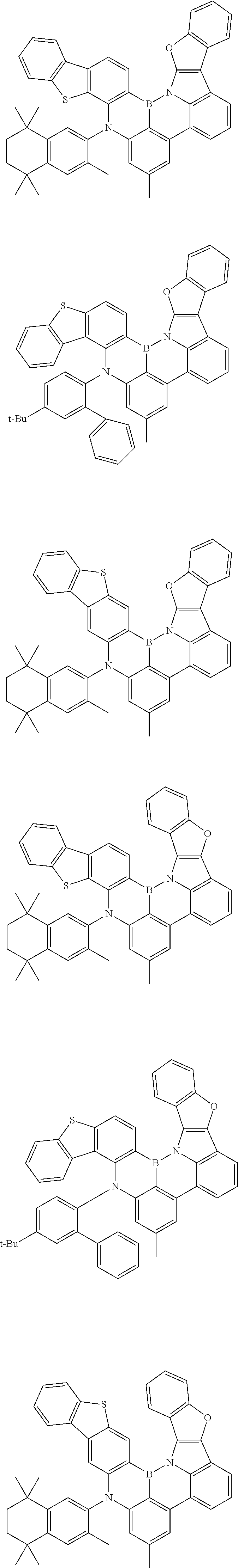 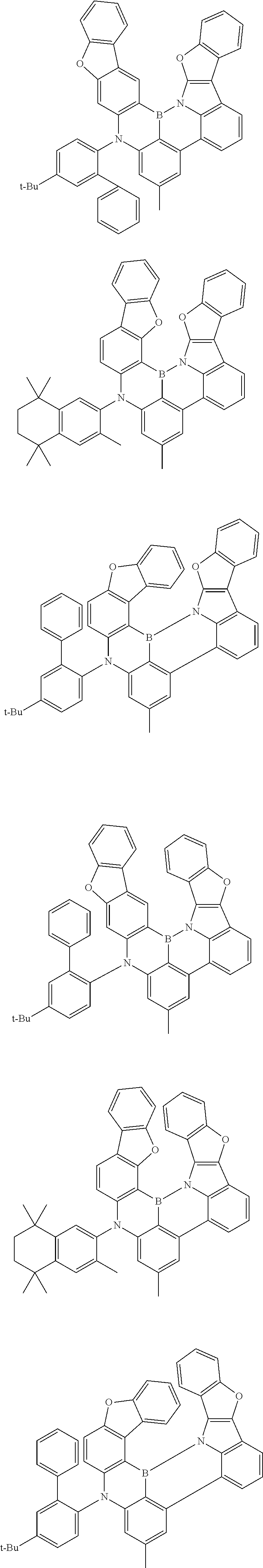 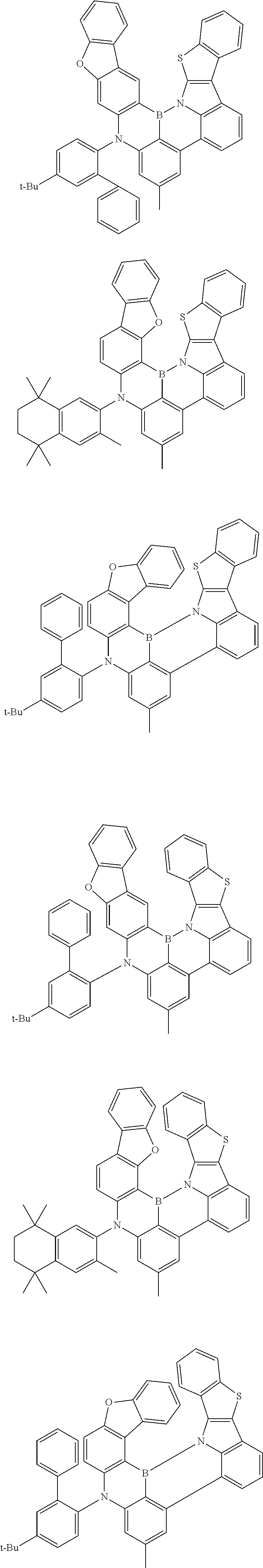 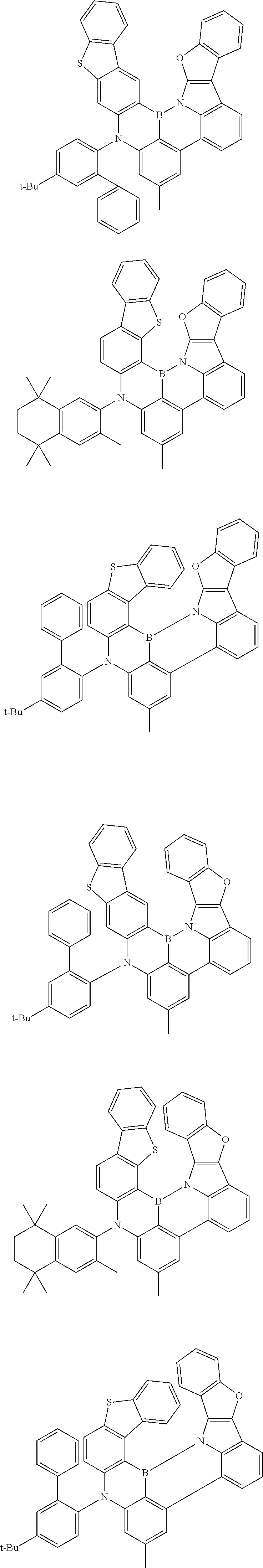 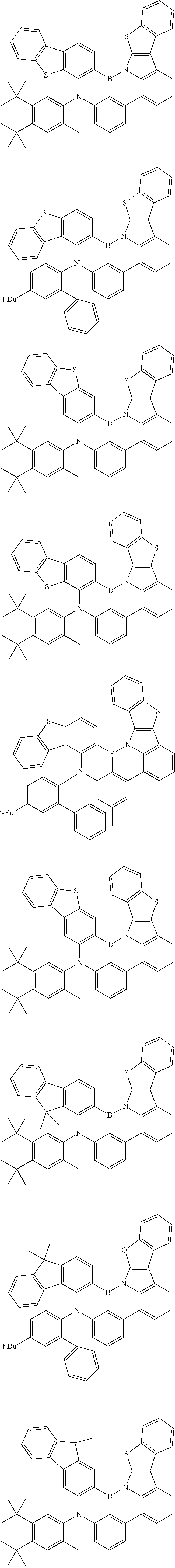 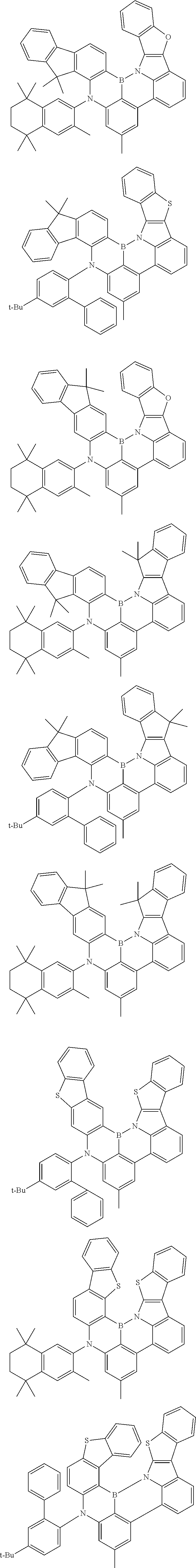 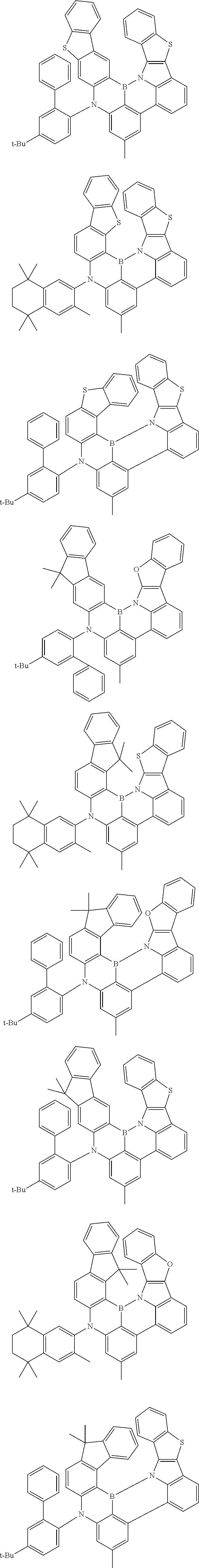 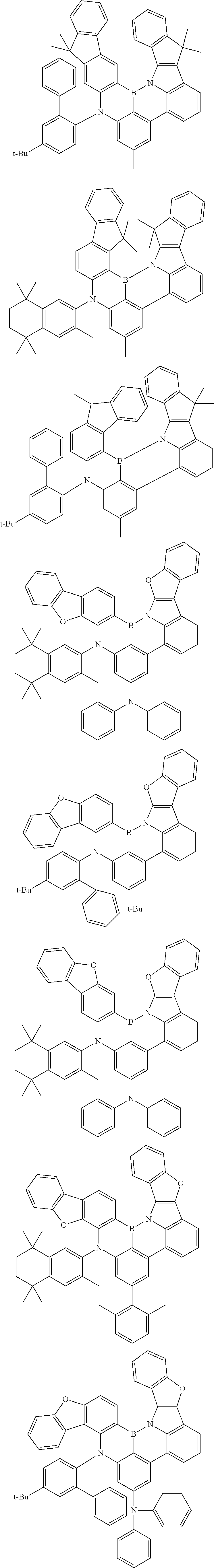 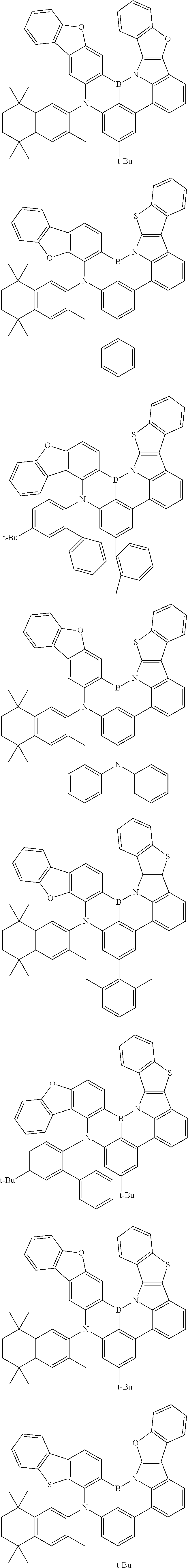 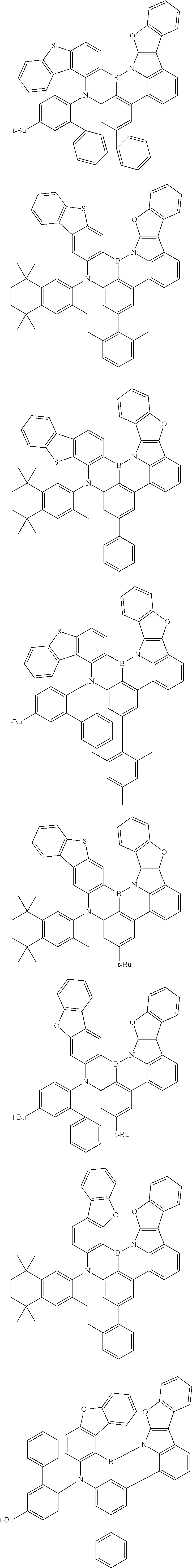 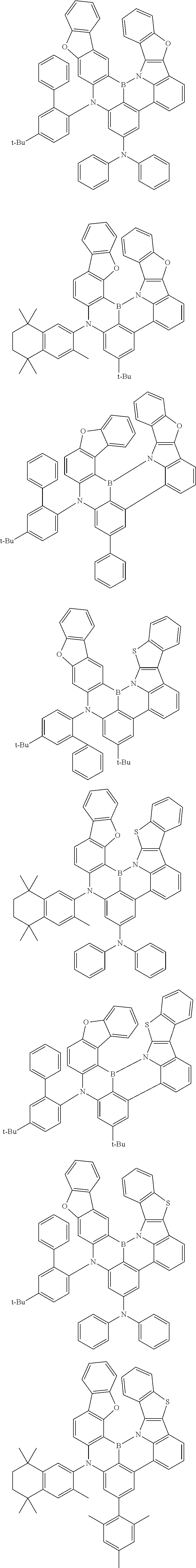 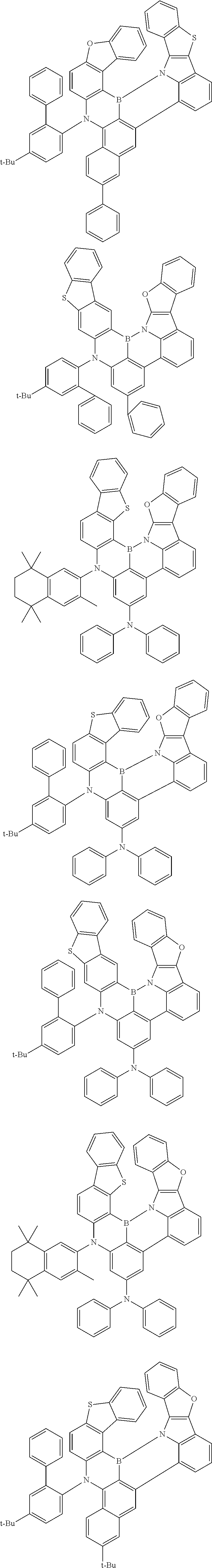 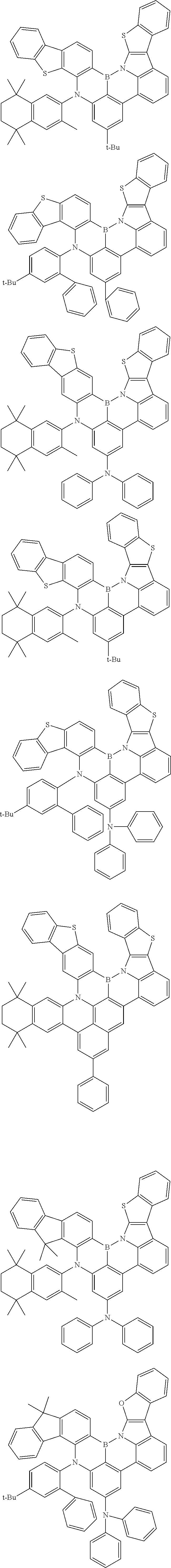 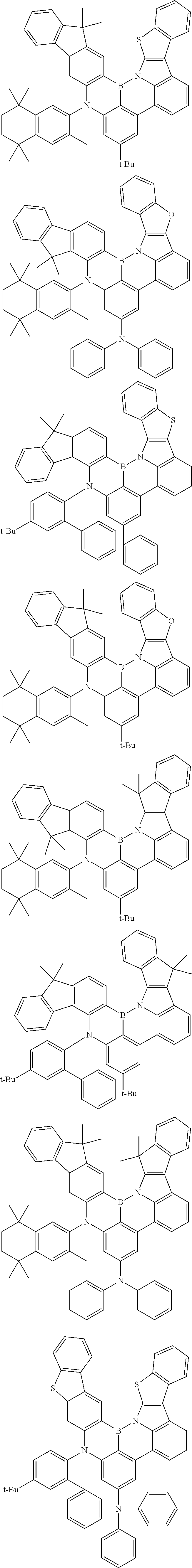 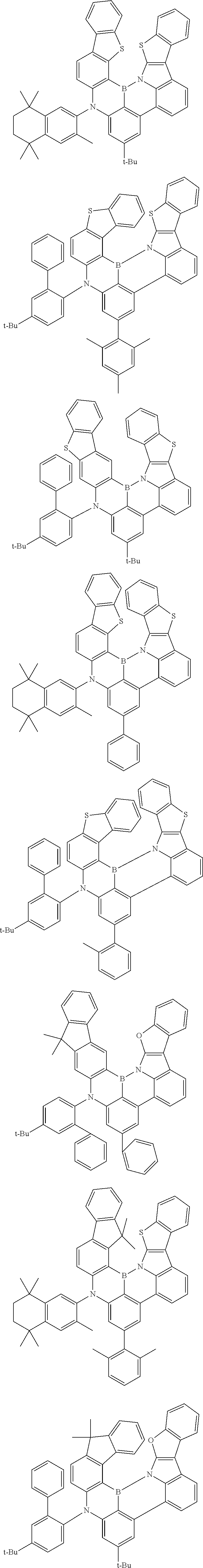 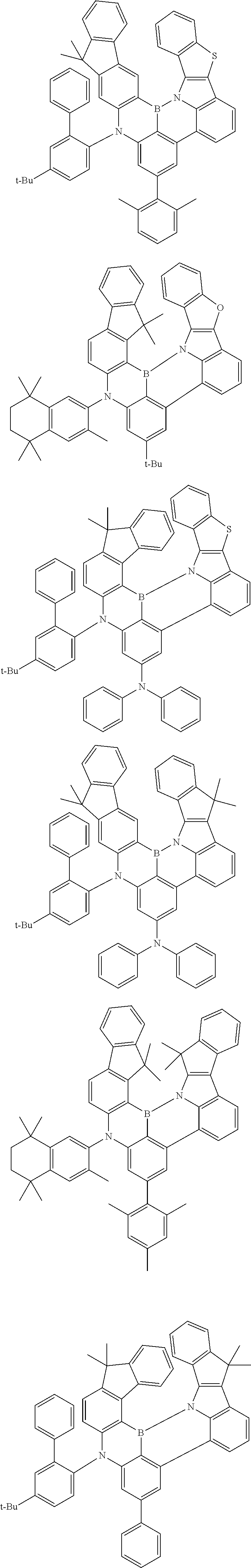 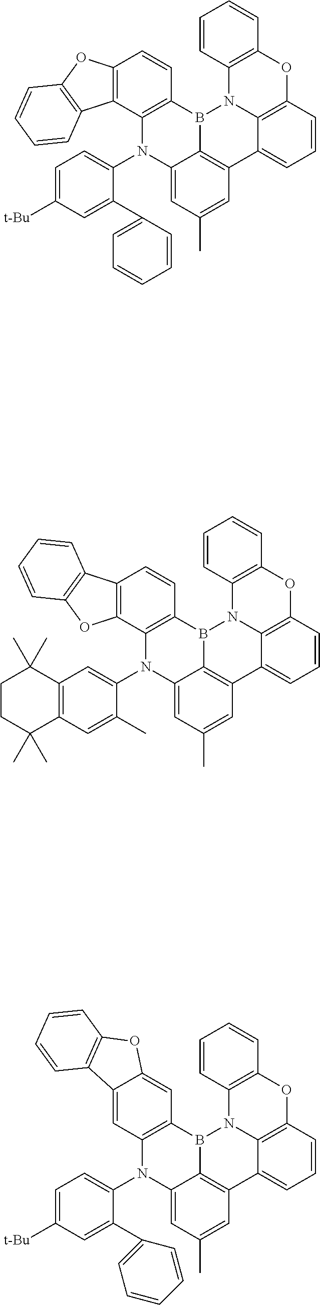 [SMILES: Cc1cc2c3c(c1)N(c1ccc(C(C)(C)C)cc1-c1ccccc1)c1c(ccc4oc5ccccc5c14)B3N1c3ccccc3Oc3cccc-2c31 ; Cc1cc2c3c(c1)N(c1cc4c(cc1C)C(C)(C)CCC4(C)C)c1c(ccc4c1oc1ccccc14)B3N1c3ccccc3Oc3cccc-2c31 ; Cc1cc2c3c(c1)N(c1ccc(C(C)(C)C)cc1-c1ccccc1)c1cc4c(cc1B3N1c3ccccc3Oc3cccc-2c31)oc1ccccc14] 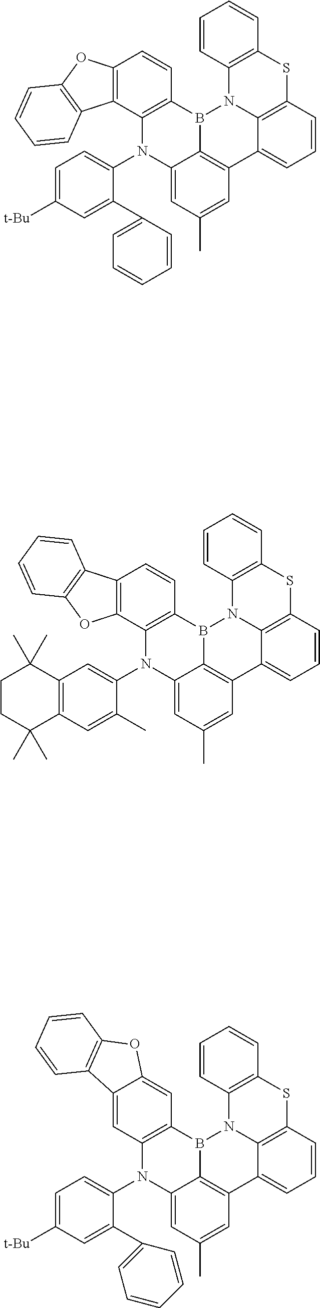 [SMILES: Cc1cc2c3c(c1)N(c1ccc(C(C)(C)C)cc1-c1ccccc1)c1c(ccc4oc5ccccc5c14)B3N1c3ccccc3Sc3cccc-2c31 ; Cc1cc2c3c(c1)N(c1cc4c(cc1C)C(C)(C)CCC4(C)C)c1c(ccc4c1oc1ccccc14)B3N1c3ccccc3Sc3cccc-2c31 ; Cc1cc2c3c(c1)N(c1ccc(C(C)(C)C)cc1-c1ccccc1)c1cc4c(cc1B3N1c3ccccc3Sc3cccc-2c31)oc1ccccc14] 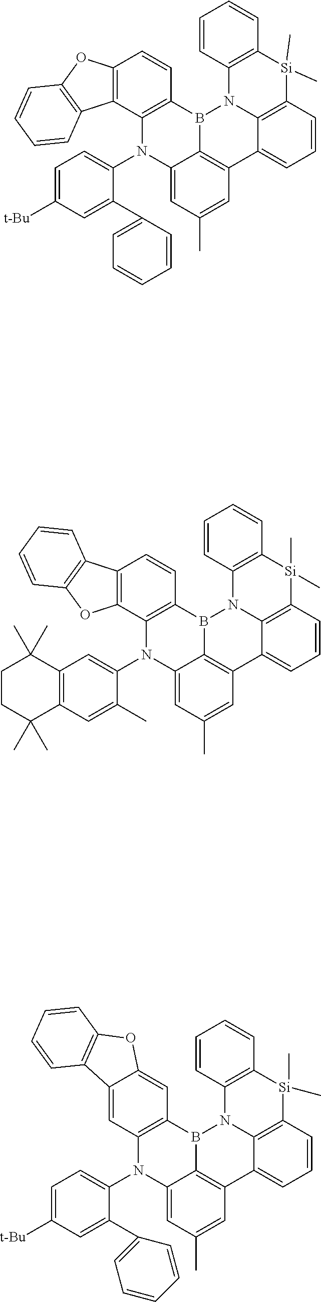 [SMILES: Cc1cc2c3c(c1)N(c1ccc(C(C)(C)C)cc1-c1ccccc1)c1c(ccc4oc5ccccc5c14)B3N1c3ccccc3[Si](C)(C)c3cccc-2c31 ; Cc1cc2c3c(c1)N(c1cc4c(cc1C)C(C)(C)CCC4(C)C)c1c(ccc4c1oc1ccccc14)B3N1c3ccccc3[Si](C)(C)c3cccc-2c31 ; Cc1cc2c3c(c1)N(c1ccc(C(C)(C)C)cc1-c1ccccc1)c1cc4c(cc1B3N1c3ccccc3[Si](C)(C)c3cccc-2c31)oc1ccccc14] 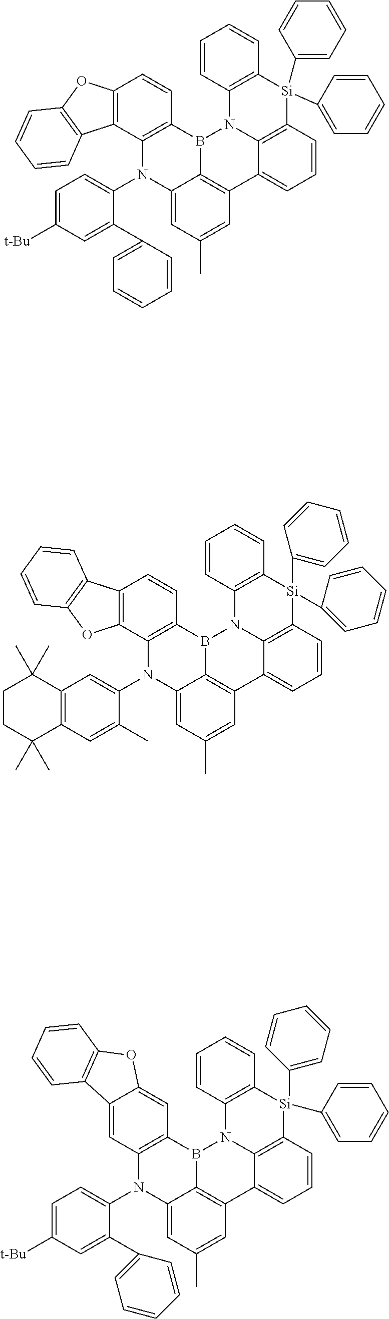 [SMILES: Cc1cc2c3c(c1)N(c1ccc(C(C)(C)C)cc1-c1ccccc1)c1c(ccc4oc5ccccc5c14)B3N1c3ccccc3[Si](c3ccccc3)(c3ccccc3)c3cccc-2c31 ; Cc1cc2c3c(c1)N(c1cc4c(cc1C)C(C)(C)CCC4(C)C)c1c(ccc4c1oc1ccccc14)B3N1c3ccccc3[Si](c3ccccc3)(c3ccccc3)c3cccc-2c31 ; Cc1cc2c3c(c1)N(c1ccc(C(C)(C)C)cc1-c1ccccc1)c1cc4c(cc1B3N1c3ccccc3[Si](c3ccccc3)(c3ccccc3)c3cccc-2c31)oc1ccccc14] 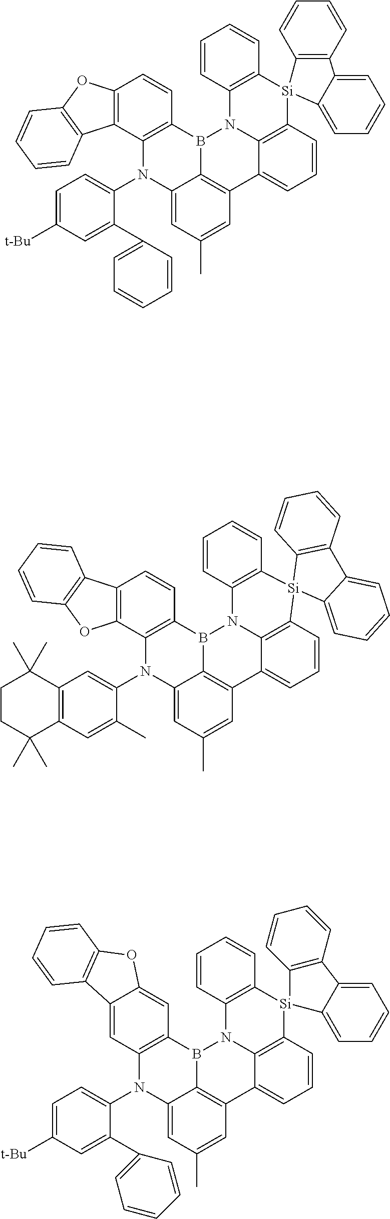 [SMILES: Cc1cc2c3c(c1)N(c1ccc(C(C)(C)C)cc1-c1ccccc1)c1c(ccc4oc5ccccc5c14)B3N1c3ccccc3[Si]3(c4ccccc4-c4ccccc43)c3cccc-2c31 ; Cc1cc2c3c(c1)N(c1cc4c(cc1C)C(C)(C)CCC4(C)C)c1c(ccc4c1oc1ccccc14)B3N1c3ccccc3[Si]3(c4ccccc4-c4ccccc43)c3cccc-2c31 ; Cc1cc2c3c(c1)N(c1ccc(C(C)(C)C)cc1-c1ccccc1)c1cc4c(cc1B3N1c3ccccc3[Si]3(c5ccccc5-c5ccccc53)c3cccc-2c31)oc1ccccc14] 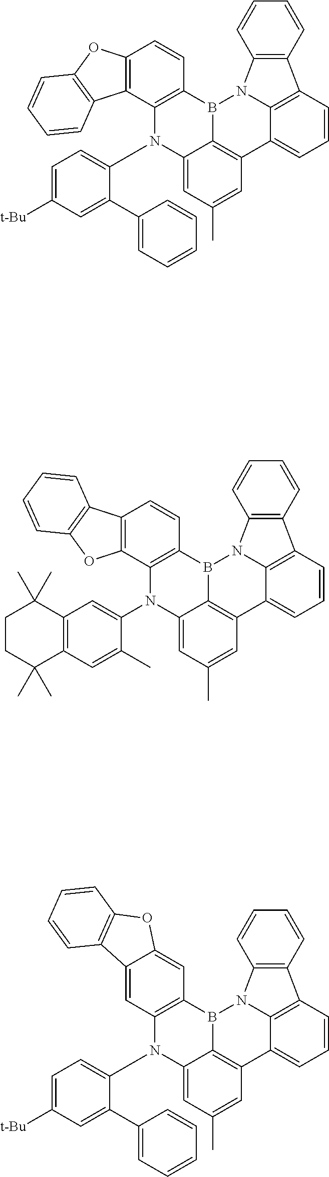 [SMILES: Cc1cc2c3c(c1)N(c1ccc(C(C)(C)C)cc1-c1ccccc1)c1c(ccc4oc5ccccc5c14)B3n1c3ccccc3c3cccc-2c31 ; Cc1cc2c3c(c1)N(c1cc4c(cc1C)C(C)(C)CCC4(C)C)c1c(ccc4c1oc1ccccc14)B3n1c3ccccc3c3cccc-2c31 ; Cc1cc2c3c(c1)N(c1ccc(C(C)(C)C)cc1-c1ccccc1)c1cc4c(cc1B3n1c3ccccc3c3cccc-2c31)oc1ccccc14] 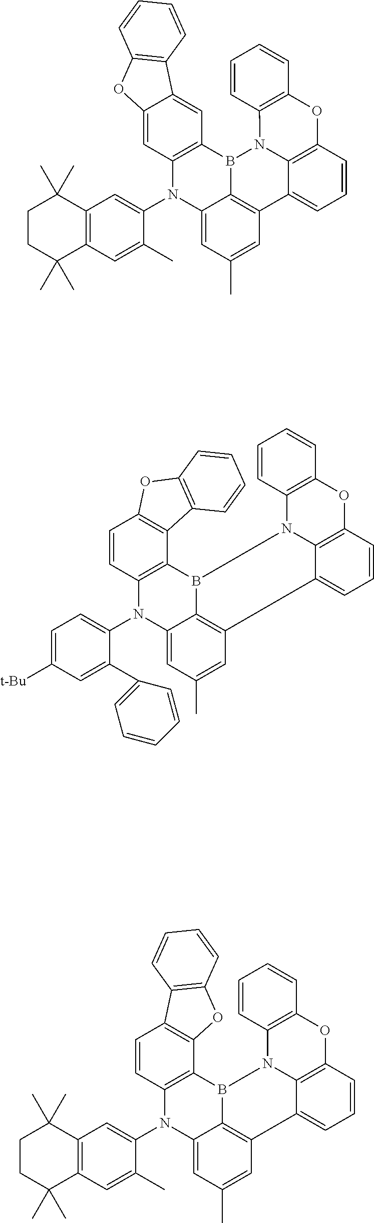 [SMILES: Cc1cc2c3c(c1)N(c1cc4c(cc1C)C(C)(C)CCC4(C)C)c1cc4oc5ccccc5c4cc1B3N1c3ccccc3Oc3cccc-2c31 ; Cc1cc2c3c(c1)N(c1ccc(C(C)(C)C)cc1-c1ccccc1)c1ccc4oc5ccccc5c4c1B3N1c3ccccc3Oc3cccc-2c31 ; Cc1cc2c3c(c1)N(c1cc4c(cc1C)C(C)(C)CCC4(C)C)c1ccc4c(oc5ccccc54)c1B3N1c3ccccc3Oc3cccc-2c31] 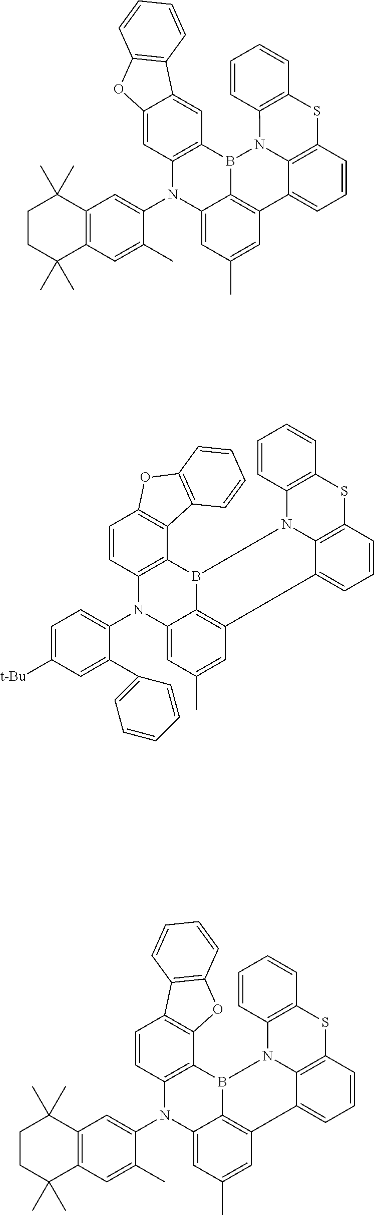 [SMILES: Cc1cc2c3c(c1)N(c1cc4c(cc1C)C(C)(C)CCC4(C)C)c1cc4oc5ccccc5c4cc1B3N1c3ccccc3Sc3cccc-2c31 ; Cc1cc2c3c(c1)N(c1ccc(C(C)(C)C)cc1-c1ccccc1)c1ccc4oc5ccccc5c4c1B3N1c3ccccc3Sc3cccc-2c31 ; Cc1cc2c3c(c1)N(c1cc4c(cc1C)C(C)(C)CCC4(C)C)c1ccc4c(oc5ccccc54)c1B3N1c3ccccc3Sc3cccc-2c31] 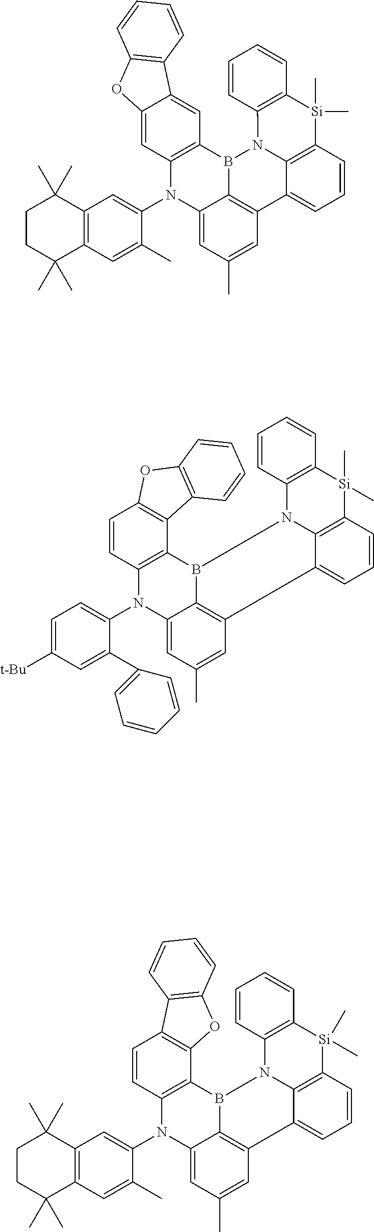 [SMILES: Cc1cc2c3c(c1)N(c1cc4c(cc1C)C(C)(C)CCC4(C)C)c1cc4oc5ccccc5c4cc1B3N1c3ccccc3[Si](C)(C)c3cccc-2c31 ; Cc1cc2c3c(c1)N(c1ccc(C(C)(C)C)cc1-c1ccccc1)c1ccc4oc5ccccc5c4c1B3N1c3ccccc3[Si](C)(C)c3cccc-2c31 ; Cc1cc2c3c(c1)N(c1cc4c(cc1C)C(C)(C)CCC4(C)C)c1ccc4c(oc5ccccc54)c1B3N1c3ccccc3[Si](C)(C)c3cccc-2c31] 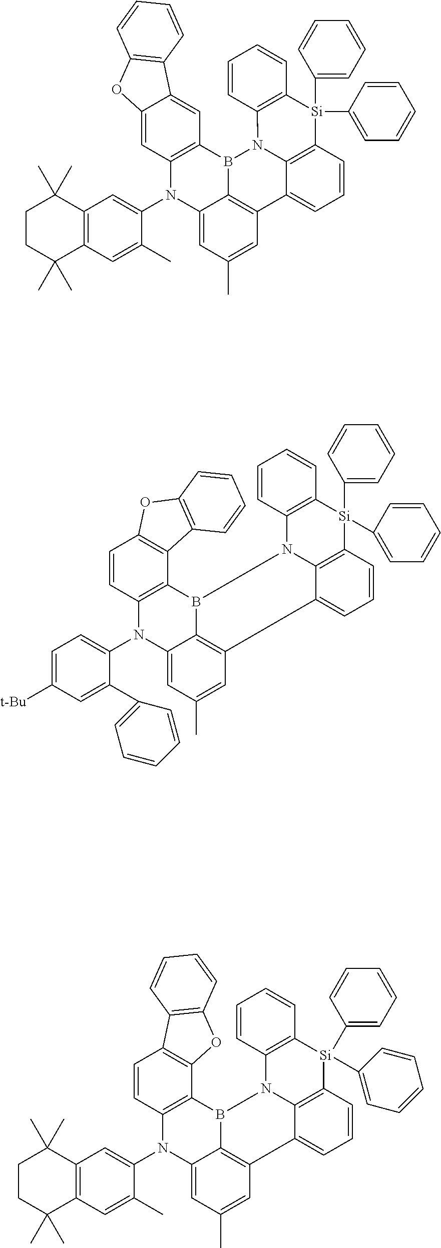 [SMILES: Cc1cc2c3c(c1)N(c1cc4c(cc1C)C(C)(C)CCC4(C)C)c1cc4oc5ccccc5c4cc1B3N1c3ccccc3[Si](c3ccccc3)(c3ccccc3)c3cccc-2c31 ; Cc1cc2c3c(c1)N(c1ccc(C(C)(C)C)cc1-c1ccccc1)c1ccc4oc5ccccc5c4c1B3N1c3ccccc3[Si](c3ccccc3)(c3ccccc3)c3cccc-2c31 ; Cc1cc2c3c(c1)N(c1cc4c(cc1C)C(C)(C)CCC4(C)C)c1ccc4c(oc5ccccc54)c1B3N1c3ccccc3[Si](c3ccccc3)(c3ccccc3)c3cccc-2c31] 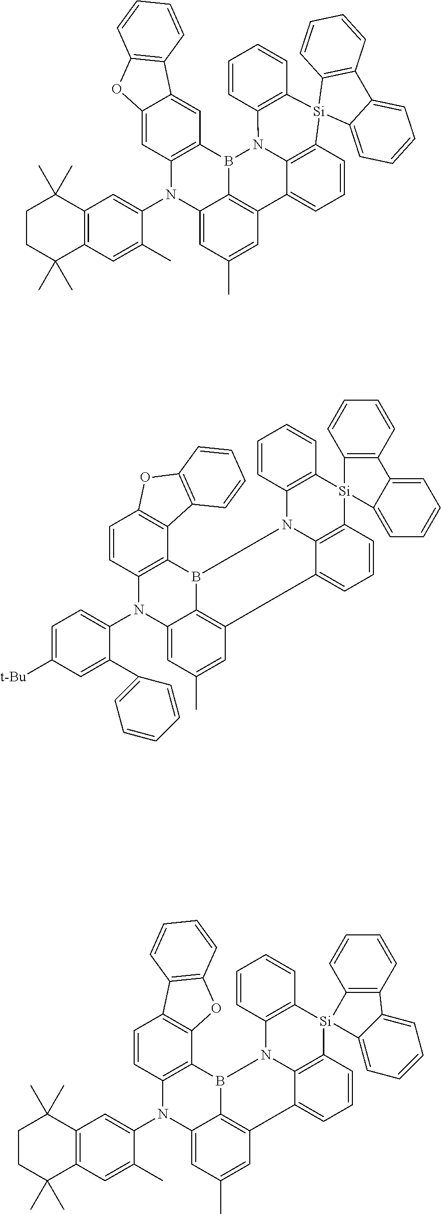 [SMILES: Cc1cc2c3c(c1)N(c1cc4c(cc1C)C(C)(C)CCC4(C)C)c1cc4oc5ccccc5c4cc1B3N1c3ccccc3[Si]3(c4ccccc4-c4ccccc43)c3cccc-2c31 ; Cc1cc2c3c(c1)N(c1ccc(C(C)(C)C)cc1-c1ccccc1)c1ccc4oc5ccccc5c4c1B3N1c3ccccc3[Si]3(c4ccccc4-c4ccccc43)c3cccc-2c31 ; Cc1cc2c3c(c1)N(c1cc4c(cc1C)C(C)(C)CCC4(C)C)c1ccc4c(oc5ccccc54)c1B3N1c3ccccc3[Si]3(c4ccccc4-c4ccccc43)c3cccc-2c31] 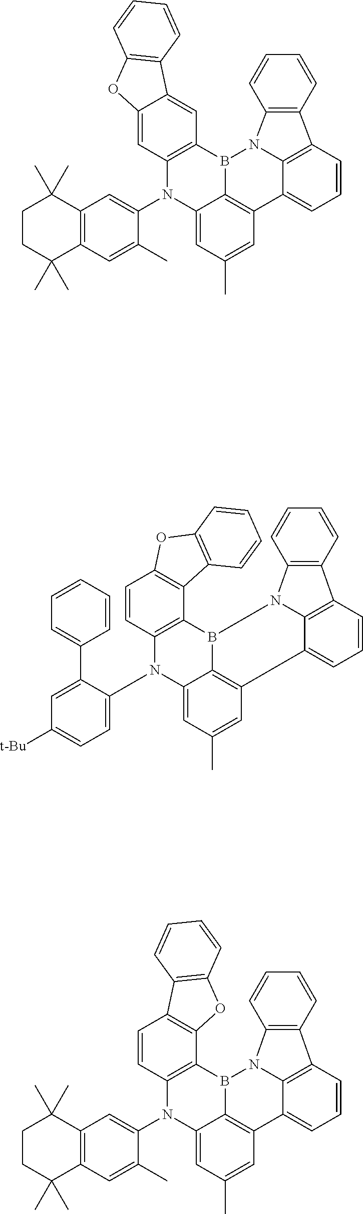 [SMILES: Cc1cc2c3c(c1)N(c1cc4c(cc1C)C(C)(C)CCC4(C)C)c1cc4oc5ccccc5c4cc1B3n1c3ccccc3c3cccc-2c31 ; Cc1cc2c3c(c1)N(c1ccc(C(C)(C)C)cc1-c1ccccc1)c1ccc4oc5ccccc5c4c1B3n1c3ccccc3c3cccc-2c31 ; Cc1cc2c3c(c1)N(c1cc4c(cc1C)C(C)(C)CCC4(C)C)c1ccc4c(oc5ccccc54)c1B3n1c3ccccc3c3cccc-2c31] 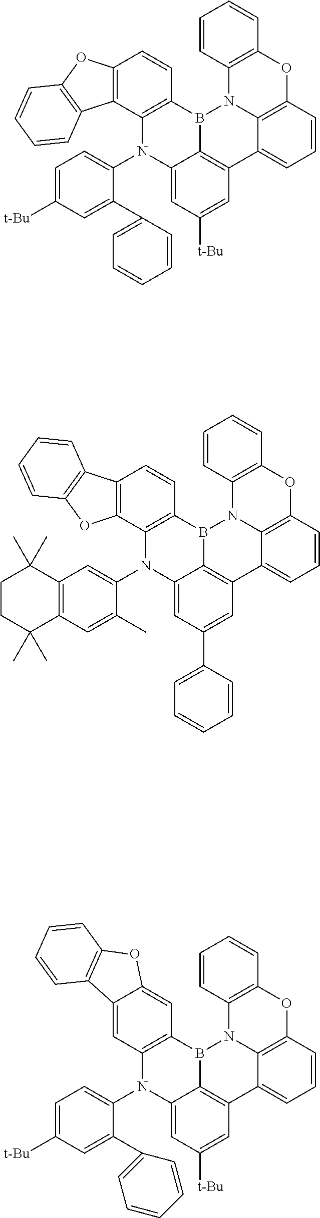 [SMILES: CC(C)(C)c1ccc(N2c3cc(C(C)(C)C)cc4c3B(c3ccc5oc6ccccc6c5c32)N2c3ccccc3Oc3cccc-4c32)c(-c2ccccc2)c1 ; Cc1cc2c(cc1N1c3cc(-c4ccccc4)cc4c3B(c3ccc5c(oc6ccccc65)c31)N1c3ccccc3Oc3cccc-4c31)C(C)(C)CCC2(C)C ; CC(C)(C)c1ccc(N2c3cc4c(cc3B3c5c(cc(C(C)(C)C)cc52)-c2cccc5c2N3c2ccccc2O5)oc2ccccc24)c(-c2ccccc2)c1] 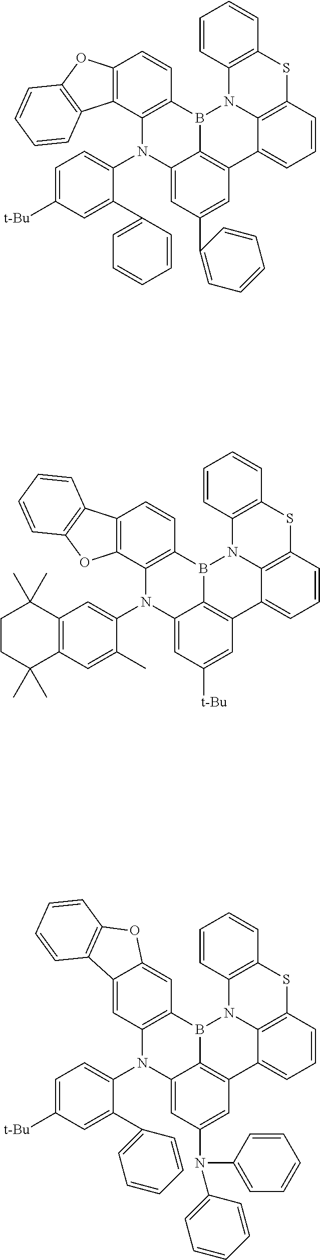 [SMILES: CC(C)(C)c1ccc(N2c3cc(-c4ccccc4)cc4c3B(c3ccc5oc6ccccc6c5c32)N2c3ccccc3Sc3cccc-4c32)c(-c2ccccc2)c1 ; Cc1cc2c(cc1N1c3cc(C(C)(C)C)cc4c3B(c3ccc5c(oc6ccccc65)c31)N1c3ccccc3Sc3cccc-4c31)C(C)(C)CCC2(C)C ; CC(C)(C)c1ccc(N2c3cc4c(cc3B3c5c(cc(N(c6ccccc6)c6ccccc6)cc52)-c2cccc5c2N3c2ccccc2S5)oc2ccccc24)c(-c2ccccc2)c1] 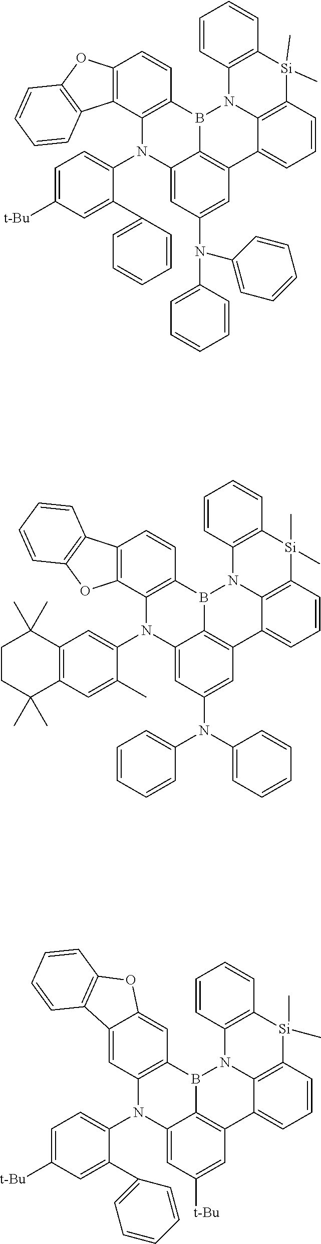 [SMILES: CC(C)(C)c1ccc(N2c3cc(N(c4ccccc4)c4ccccc4)cc4c3B(c3ccc5oc6ccccc6c5c32)N2c3ccccc3[Si](C)(C)c3cccc-4c32)c(-c2ccccc2)c1 ; Cc1cc2c(cc1N1c3cc(N(c4ccccc4)c4ccccc4)cc4c3B(c3ccc5c(oc6ccccc65)c31)N1c3ccccc3[Si](C)(C)c3cccc-4c31)C(C)(C)CCC2(C)C ; CC(C)(C)c1ccc(N2c3cc4c(cc3B3c5c(cc(C(C)(C)C)cc52)-c2cccc5c2N3c2ccccc2[Si]5(C)C)oc2ccccc24)c(-c2ccccc2)c1] 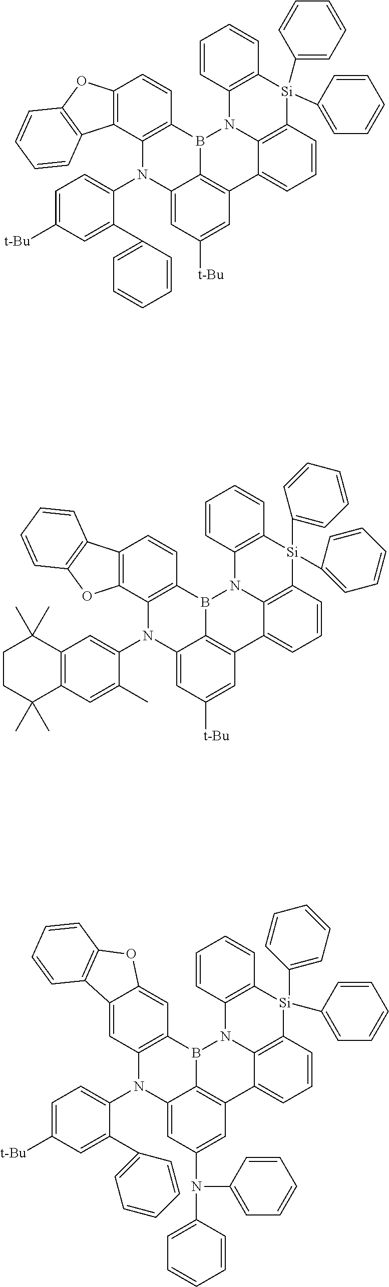 [SMILES: CC(C)(C)c1ccc(N2c3cc(C(C)(C)C)cc4c3B(c3ccc5oc6ccccc6c5c32)N2c3ccccc3[Si](c3ccccc3)(c3ccccc3)c3cccc-4c32)c(-c2ccccc2)c1 ; Cc1cc2c(cc1N1c3cc(C(C)(C)C)cc4c3B(c3ccc5c(oc6ccccc65)c31)N1c3ccccc3[Si](c3ccccc3)(c3ccccc3)c3cccc-4c31)C(C)(C)CCC2(C)C ; CC(C)(C)c1ccc(N2c3cc4c(cc3B3c5c(cc(N(c6ccccc6)c6ccccc6)cc52)-c2cccc5c2N3c2ccccc2[Si]5(c2ccccc2)c2ccccc2)oc2ccccc24)c(-c2ccccc2)c1] 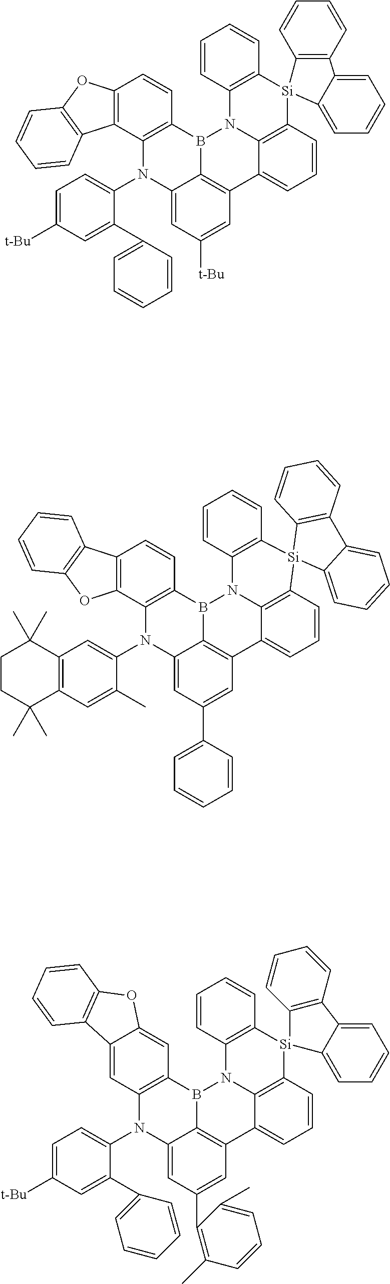 [SMILES: CC(C)(C)c1ccc(N2c3cc(C(C)(C)C)cc4c3B(c3ccc5oc6ccccc6c5c32)N2c3ccccc3[Si]3(c5ccccc5-c5ccccc53)c3cccc-4c32)c(-c2ccccc2)c1 ; Cc1cc2c(cc1N1c3cc(-c4ccccc4)cc4c3B(c3ccc5c(oc6ccccc65)c31)N1c3ccccc3[Si]3(c5ccccc5-c5ccccc53)c3cccc-4c31)C(C)(C)CCC2(C)C ; Cc1cccc(C)c1-c1cc2c3c(c1)N(c1ccc(C(C)(C)C)cc1-c1ccccc1)c1cc4c(cc1B3N1c3ccccc3[Si]3(c5ccccc5-c5ccccc53)c3cccc-2c31)oc1ccccc14] 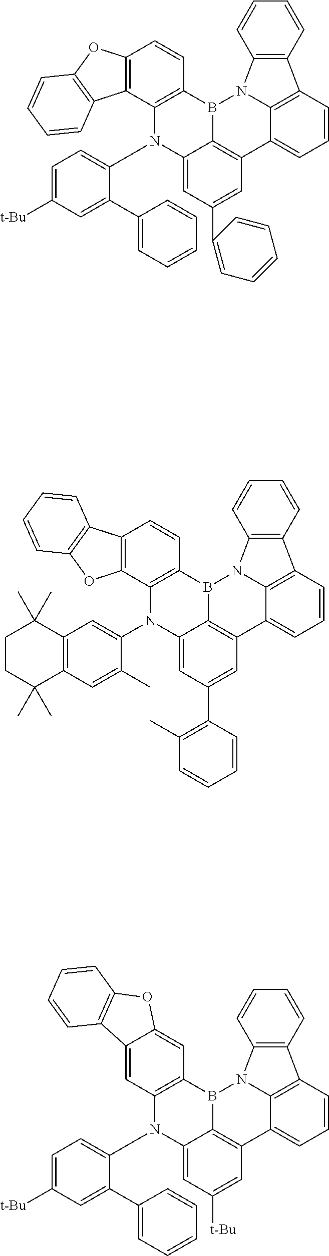 [SMILES: CC(C)(C)c1ccc(N2c3cc(-c4ccccc4)cc4c3B(c3ccc5oc6ccccc6c5c32)n2c3ccccc3c3cccc-4c32)c(-c2ccccc2)c1 ; Cc1ccccc1-c1cc2c3c(c1)N(c1cc4c(cc1C)C(C)(C)CCC4(C)C)c1c(ccc4c1oc1ccccc14)B3n1c3ccccc3c3cccc-2c31 ; CC(C)(C)c1ccc(N2c3cc4c(cc3B3c5c(cc(C(C)(C)C)cc52)-c2cccc5c6ccccc6n3c25)oc2ccccc24)c(-c2ccccc2)c1] 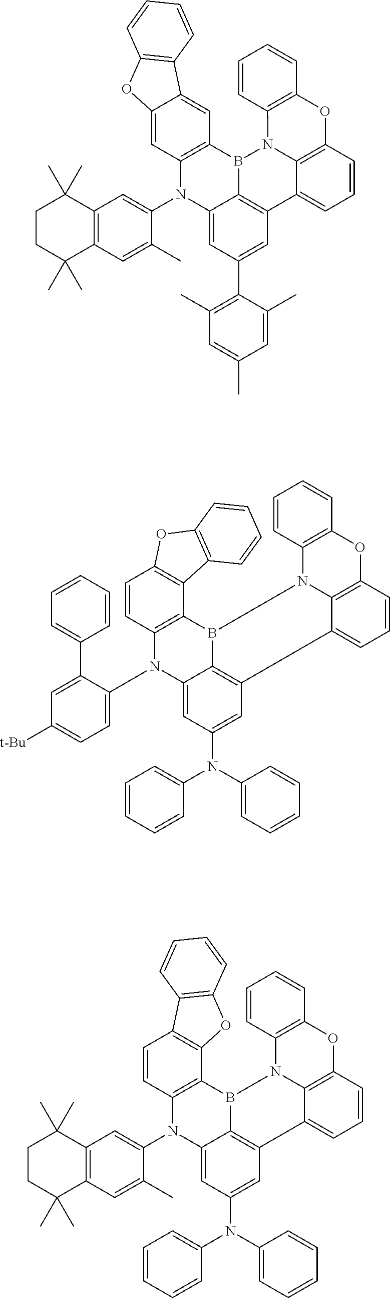 [SMILES: Cc1cc(C)c(-c2cc3c4c(c2)N(c2cc5c(cc2C)C(C)(C)CCC5(C)C)c2cc5oc6ccccc6c5cc2B4N2c4ccccc4Oc4cccc-3c42)c(C)c1 ; CC(C)(C)c1ccc(N2c3cc(N(c4ccccc4)c4ccccc4)cc4c3B(c3c2ccc2oc5ccccc5c32)N2c3ccccc3Oc3cccc-4c32)c(-c2ccccc2)c1 ; Cc1cc2c(cc1N1c3cc(N(c4ccccc4)c4ccccc4)cc4c3B(c3c1ccc1c3oc3ccccc31)N1c3ccccc3Oc3cccc-4c31)C(C)(C)CCC2(C)C] 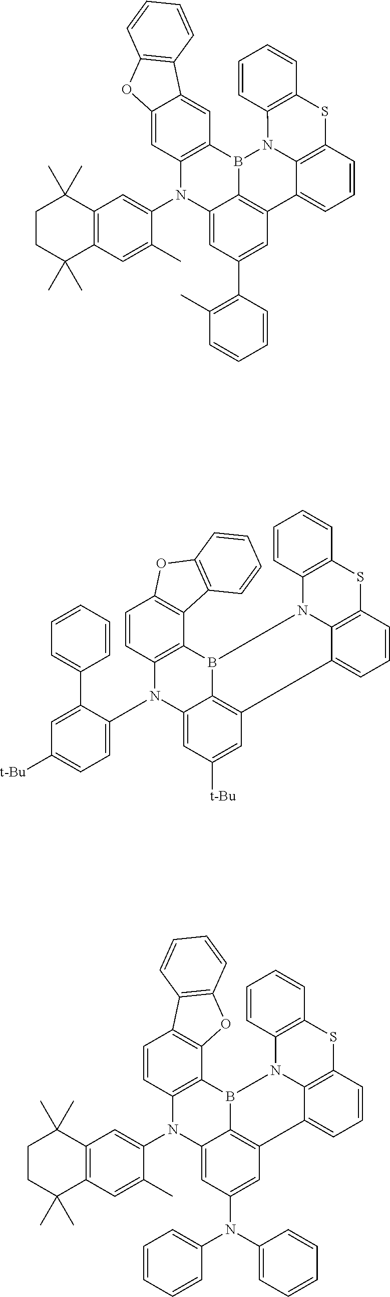 [SMILES: Cc1ccccc1-c1cc2c3c(c1)N(c1cc4c(cc1C)C(C)(C)CCC4(C)C)c1cc4oc5ccccc5c4cc1B3N1c3ccccc3Sc3cccc-2c31 ; CC(C)(C)c1ccc(N2c3cc(C(C)(C)C)cc4c3B(c3c2ccc2oc5ccccc5c32)N2c3ccccc3Sc3cccc-4c32)c(-c2ccccc2)c1 ; Cc1cc2c(cc1N1c3cc(N(c4ccccc4)c4ccccc4)cc4c3B(c3c1ccc1c3oc3ccccc31)N1c3ccccc3Sc3cccc-4c31)C(C)(C)CCC2(C)C] 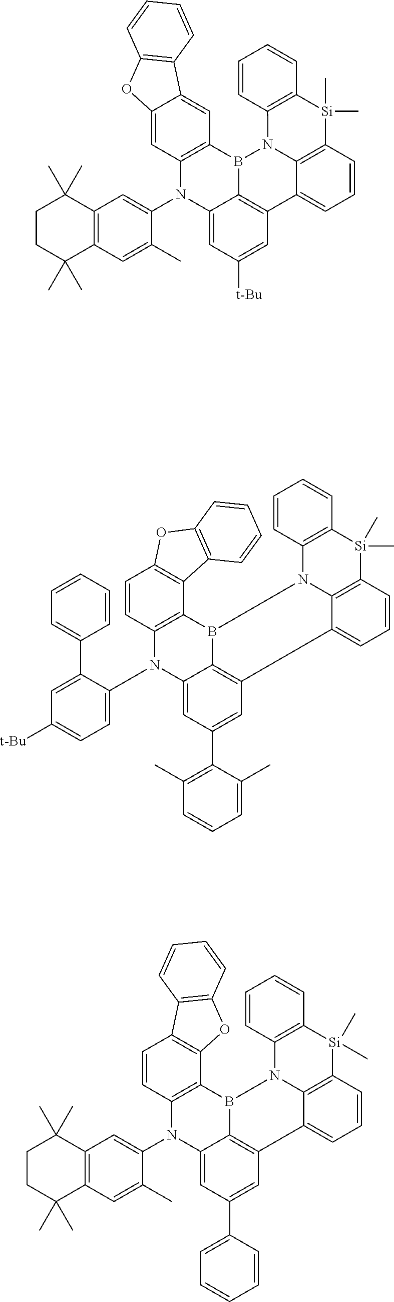 [SMILES: Cc1cc2c(cc1N1c3cc4oc5ccccc5c4cc3B3c4c(cc(C(C)(C)C)cc41)-c1cccc4c1N3c1ccccc1[Si]4(C)C)C(C)(C)CCC2(C)C ; Cc1cccc(C)c1-c1cc2c3c(c1)N(c1ccc(C(C)(C)C)cc1-c1ccccc1)c1ccc4oc5ccccc5c4c1B3N1c3ccccc3[Si](C)(C)c3cccc-2c31 ; Cc1cc2c(cc1N1c3cc(-c4ccccc4)cc4c3B(c3c1ccc1c3oc3ccccc31)N1c3ccccc3[Si](C)(C)c3cccc-4c31)C(C)(C)CCC2(C)C] 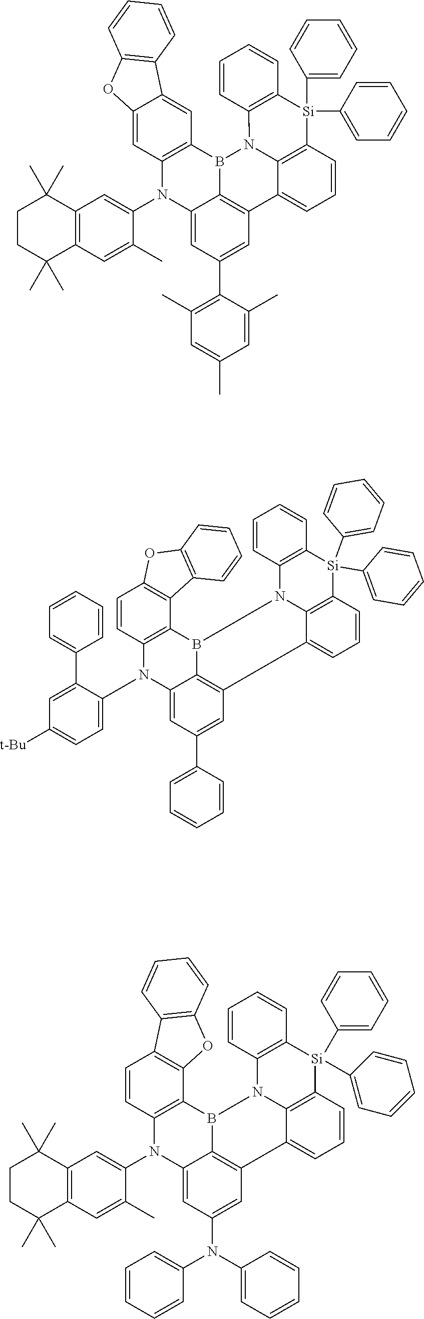 [SMILES: Cc1cc(C)c(-c2cc3c4c(c2)N(c2cc5c(cc2C)C(C)(C)CCC5(C)C)c2cc5oc6ccccc6c5cc2B4N2c4ccccc4[Si](c4ccccc4)(c4ccccc4)c4cccc-3c42)c(C)c1 ; CC(C)(C)c1ccc(N2c3cc(-c4ccccc4)cc4c3B(c3c2ccc2oc5ccccc5c32)N2c3ccccc3[Si](c3ccccc3)(c3ccccc3)c3cccc-4c32)c(-c2ccccc2)c1 ; Cc1cc2c(cc1N1c3cc(N(c4ccccc4)c4ccccc4)cc4c3B(c3c1ccc1c3oc3ccccc31)N1c3ccccc3[Si](c3ccccc3)(c3ccccc3)c3cccc-4c31)C(C)(C)CCC2(C)C] 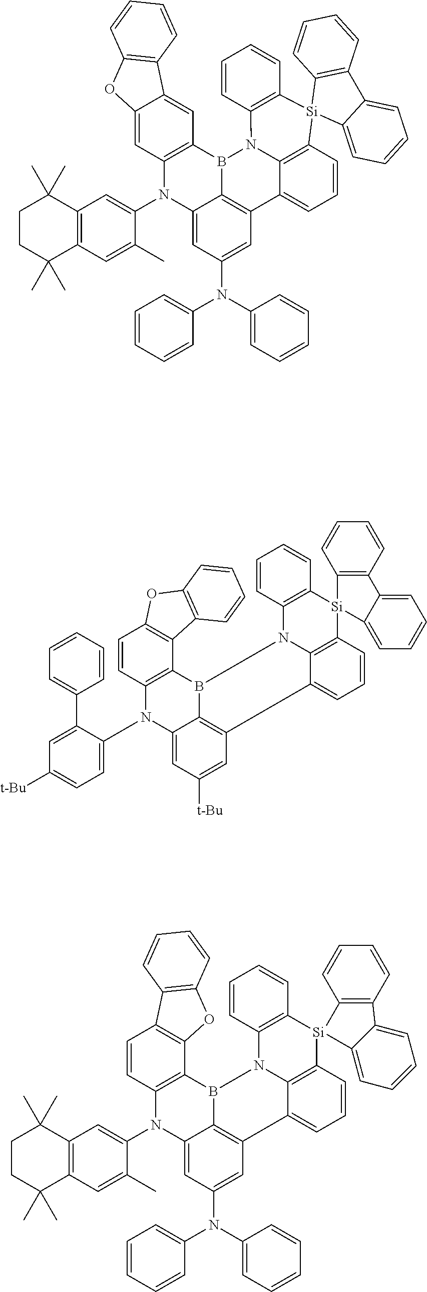 [SMILES: Cc1cc2c(cc1N1c3cc4oc5ccccc5c4cc3B3c4c(cc(N(c5ccccc5)c5ccccc5)cc41)-c1cccc4c1N3c1ccccc1[Si]41c3ccccc3-c3ccccc31)C(C)(C)CCC2(C)C ; CC(C)(C)c1ccc(N2c3cc(C(C)(C)C)cc4c3B(c3c2ccc2oc5ccccc5c32)N2c3ccccc3[Si]3(c5ccccc5-c5ccccc53)c3cccc-4c32)c(-c2ccccc2)c1 ; Cc1cc2c(cc1N1c3cc(N(c4ccccc4)c4ccccc4)cc4c3B(c3c1ccc1c3oc3ccccc31)N1c3ccccc3[Si]3(c5ccccc5-c5ccccc53)c3cccc-4c31)C(C)(C)CCC2(C)C] 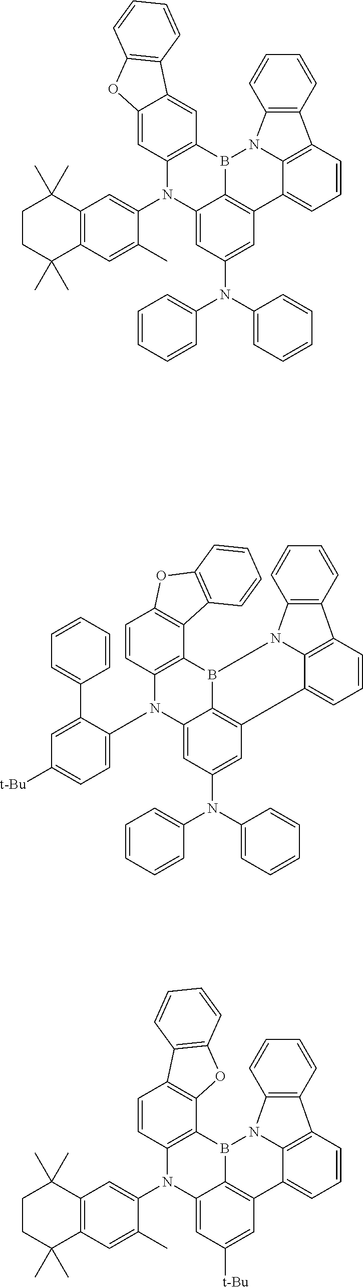 [SMILES: Cc1cc2c(cc1N1c3cc4oc5ccccc5c4cc3B3c4c(cc(N(c5ccccc5)c5ccccc5)cc41)-c1cccc4c5ccccc5n3c14)C(C)(C)CCC2(C)C ; CC(C)(C)c1ccc(N2c3cc(N(c4ccccc4)c4ccccc4)cc4c3B(c3c2ccc2oc5ccccc5c32)n2c3ccccc3c3cccc-4c32)c(-c2ccccc2)c1 ; Cc1cc2c(cc1N1c3cc(C(C)(C)C)cc4c3B(c3c1ccc1c3oc3ccccc31)n1c3ccccc3c3cccc-4c31)C(C)(C)CCC2(C)C] 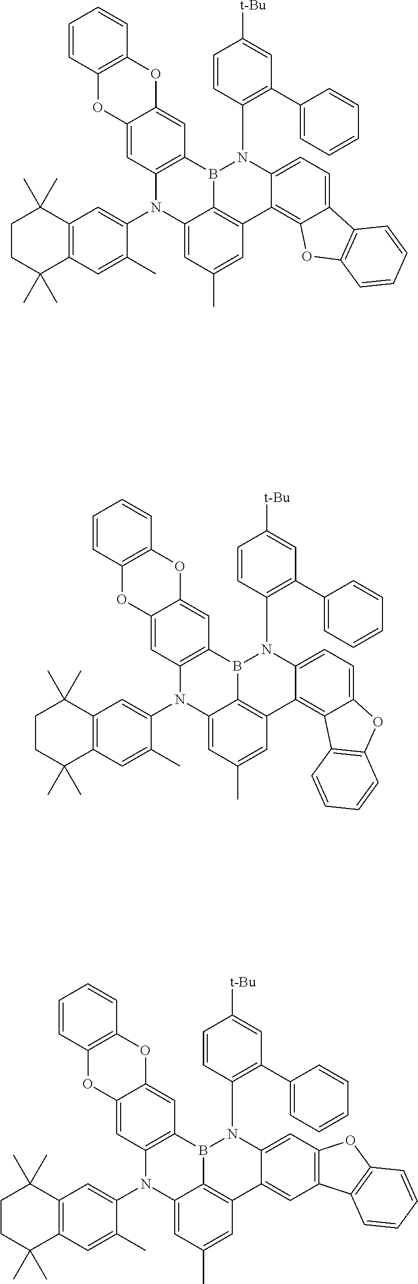 [SMILES: Cc1cc2c3c(c1)N(c1cc4c(cc1C)C(C)(C)CCC4(C)C)c1cc4c(cc1B3N(c1ccc(C(C)(C)C)cc1-c1ccccc1)c1ccc3c(oc5ccccc53)c1-2)Oc1ccccc1O4 ; Cc1cc2c3c(c1)N(c1cc4c(cc1C)C(C)(C)CCC4(C)C)c1cc4c(cc1B3N(c1ccc(C(C)(C)C)cc1-c1ccccc1)c1ccc3oc5ccccc5c3c1-2)Oc1ccccc1O4 ; Cc1cc2c3c(c1)N(c1cc4c(cc1C)C(C)(C)CCC4(C)C)c1cc4c(cc1B3N(c1ccc(C(C)(C)C)cc1-c1ccccc1)c1cc3oc5ccccc5c3cc1-2)Oc1ccccc1O4] 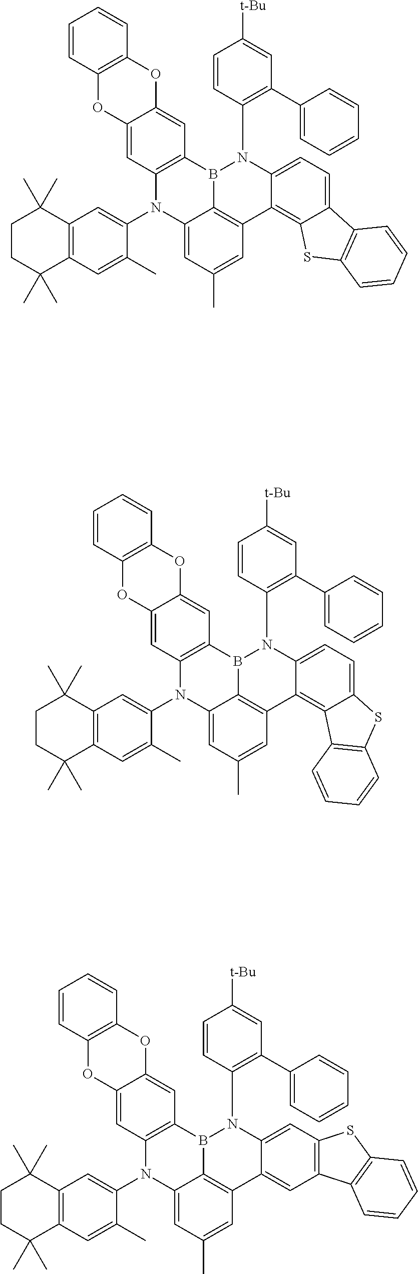 [SMILES: Cc1cc2c3c(c1)N(c1cc4c(cc1C)C(C)(C)CCC4(C)C)c1cc4c(cc1B3N(c1ccc(C(C)(C)C)cc1-c1ccccc1)c1ccc3c(sc5ccccc53)c1-2)Oc1ccccc1O4 ; Cc1cc2c3c(c1)N(c1cc4c(cc1C)C(C)(C)CCC4(C)C)c1cc4c(cc1B3N(c1ccc(C(C)(C)C)cc1-c1ccccc1)c1ccc3sc5ccccc5c3c1-2)Oc1ccccc1O4 ; Cc1cc2c3c(c1)N(c1cc4c(cc1C)C(C)(C)CCC4(C)C)c1cc4c(cc1B3N(c1ccc(C(C)(C)C)cc1-c1ccccc1)c1cc3sc5ccccc5c3cc1-2)Oc1ccccc1O4] 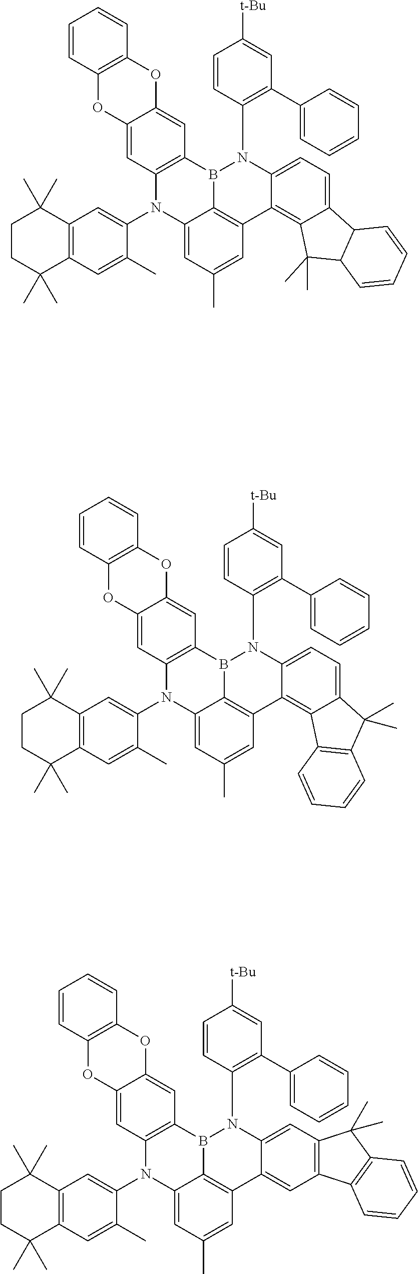 [SMILES: Cc1cc2c3c(c1)N(c1cc4c(cc1C)C(C)(C)CCC4(C)C)c1cc4c(cc1B3N(c1ccc(C(C)(C)C)cc1-c1ccccc1)c1ccc3c(c1-2)C(C)(C)C1C=CC=CC31)Oc1ccccc1O4 ; Cc1cc2c3c(c1)N(c1cc4c(cc1C)C(C)(C)CCC4(C)C)c1cc4c(cc1B3N(c1ccc(C(C)(C)C)cc1-c1ccccc1)c1ccc3c(c1-2)-c1ccccc1C3(C)C)Oc1ccccc1O4 ; Cc1cc2c3c(c1)N(c1cc4c(cc1C)C(C)(C)CCC4(C)C)c1cc4c(cc1B3N(c1ccc(C(C)(C)C)cc1-c1ccccc1)c1cc3c(cc1-2)-c1ccccc1C3(C)C)Oc1ccccc1O4] 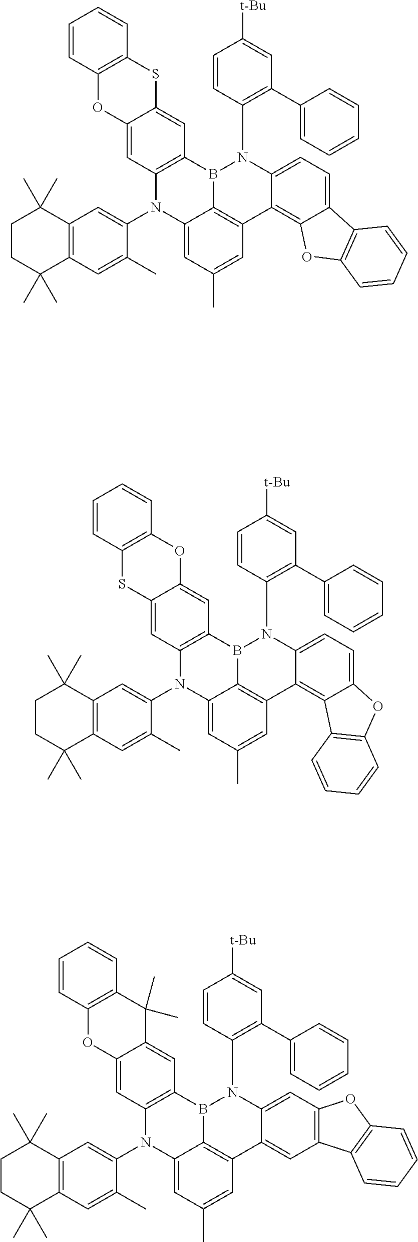 [SMILES: Cc1cc2c3c(c1)N(c1cc4c(cc1C)C(C)(C)CCC4(C)C)c1cc4c(cc1B3N(c1ccc(C(C)(C)C)cc1-c1ccccc1)c1ccc3c(oc5ccccc53)c1-2)Sc1ccccc1O4 ; Cc1cc2c3c(c1)N(c1cc4c(cc1C)C(C)(C)CCC4(C)C)c1cc4c(cc1B3N(c1ccc(C(C)(C)C)cc1-c1ccccc1)c1ccc3oc5ccccc5c3c1-2)Oc1ccccc1S4 ; Cc1cc2c3c(c1)N(c1cc4c(cc1C)C(C)(C)CCC4(C)C)c1cc4c(cc1B3N(c1ccc(C(C)(C)C)cc1-c1ccccc1)c1cc3oc5ccccc5c3cc1-2)C(C)(C)c1ccccc1O4] 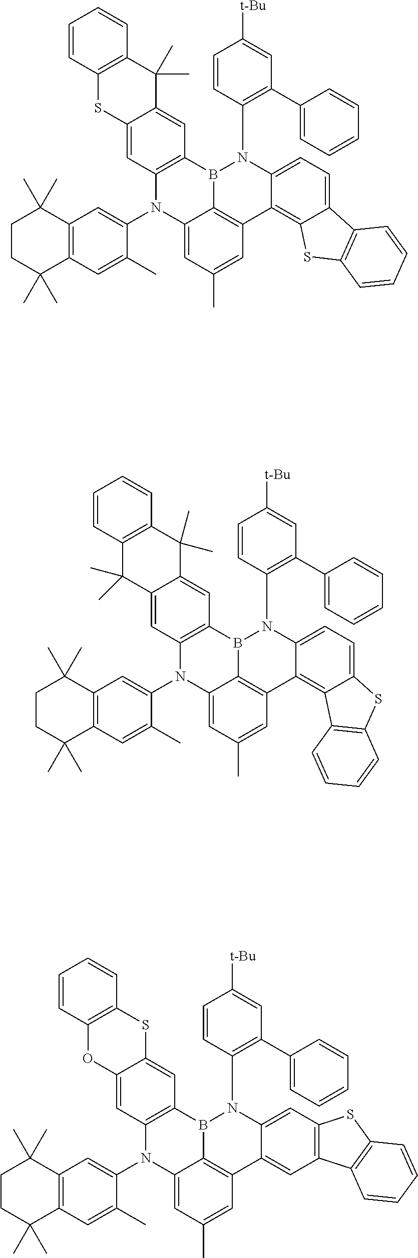 [SMILES: Cc1cc2c3c(c1)N(c1cc4c(cc1C)C(C)(C)CCC4(C)C)c1cc4c(cc1B3N(c1ccc(C(C)(C)C)cc1-c1ccccc1)c1ccc3c(sc5ccccc53)c1-2)C(C)(C)c1ccccc1S4 ; Cc1cc2c3c(c1)N(c1cc4c(cc1C)C(C)(C)CCC4(C)C)c1cc4c(cc1B3N(c1ccc(C(C)(C)C)cc1-c1ccccc1)c1ccc3sc5ccccc5c3c1-2)C(C)(C)c1ccccc1C4(C)C ; Cc1cc2c3c(c1)N(c1cc4c(cc1C)C(C)(C)CCC4(C)C)c1cc4c(cc1B3N(c1ccc(C(C)(C)C)cc1-c1ccccc1)c1cc3sc5ccccc5c3cc1-2)Sc1ccccc1O4] 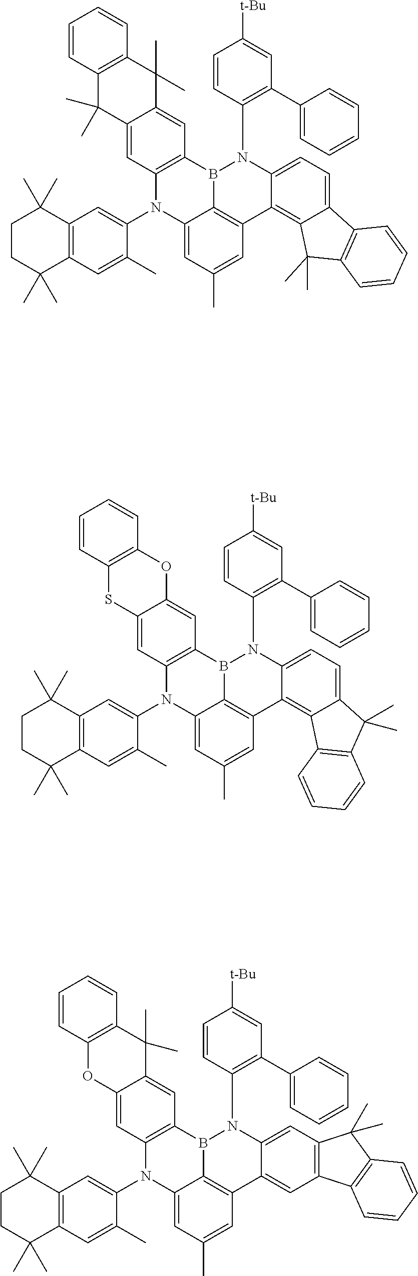 [SMILES: Cc1cc2c3c(c1)N(c1cc4c(cc1C)C(C)(C)CCC4(C)C)c1cc4c(cc1B3N(c1ccc(C(C)(C)C)cc1-c1ccccc1)c1ccc3c(c1-2)C(C)(C)c1ccccc1-3)C(C)(C)c1ccccc1C4(C)C ; Cc1cc2c3c(c1)N(c1cc4c(cc1C)C(C)(C)CCC4(C)C)c1cc4c(cc1B3N(c1ccc(C(C)(C)C)cc1-c1ccccc1)c1ccc3c(c1-2)-c1ccccc1C3(C)C)Oc1ccccc1S4 ; Cc1cc2c3c(c1)N(c1cc4c(cc1C)C(C)(C)CCC4(C)C)c1cc4c(cc1B3N(c1ccc(C(C)(C)C)cc1-c1ccccc1)c1cc3c(cc1-2)-c1ccccc1C3(C)C)C(C)(C)c1ccccc1O4] 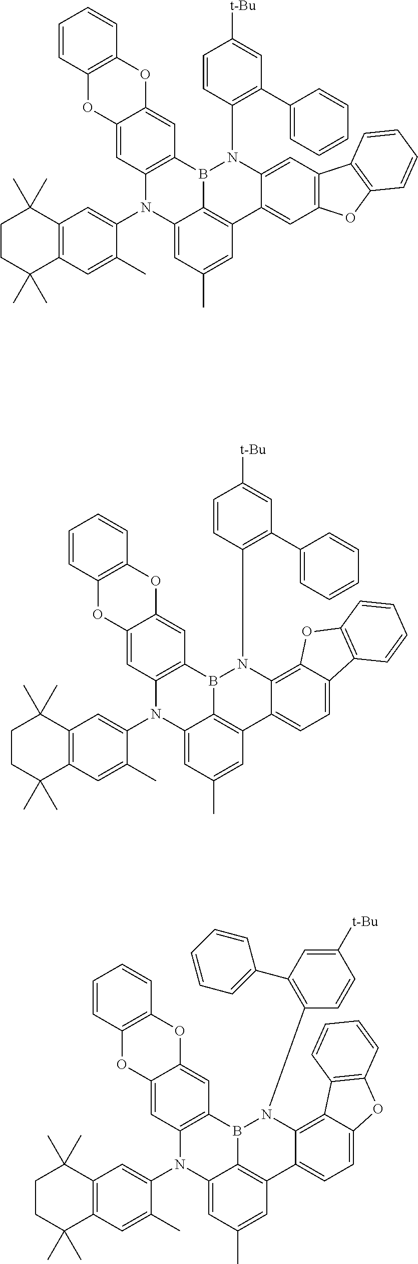 [SMILES: Cc1cc2c3c(c1)N(c1cc4c(cc1C)C(C)(C)CCC4(C)C)c1cc4c(cc1B3N(c1ccc(C(C)(C)C)cc1-c1ccccc1)c1cc3c(cc1-2)oc1ccccc13)Oc1ccccc1O4 ; Cc1cc2c3c(c1)N(c1cc4c(cc1C)C(C)(C)CCC4(C)C)c1cc4c(cc1B3N(c1ccc(C(C)(C)C)cc1-c1ccccc1)c1c-2ccc2c1oc1ccccc12)Oc1ccccc1O4 ; Cc1cc2c3c(c1)N(c1cc4c(cc1C)C(C)(C)CCC4(C)C)c1cc4c(cc1B3N(c1ccc(C(C)(C)C)cc1-c1ccccc1)c1c-2ccc2oc3ccccc3c12)Oc1ccccc1O4] 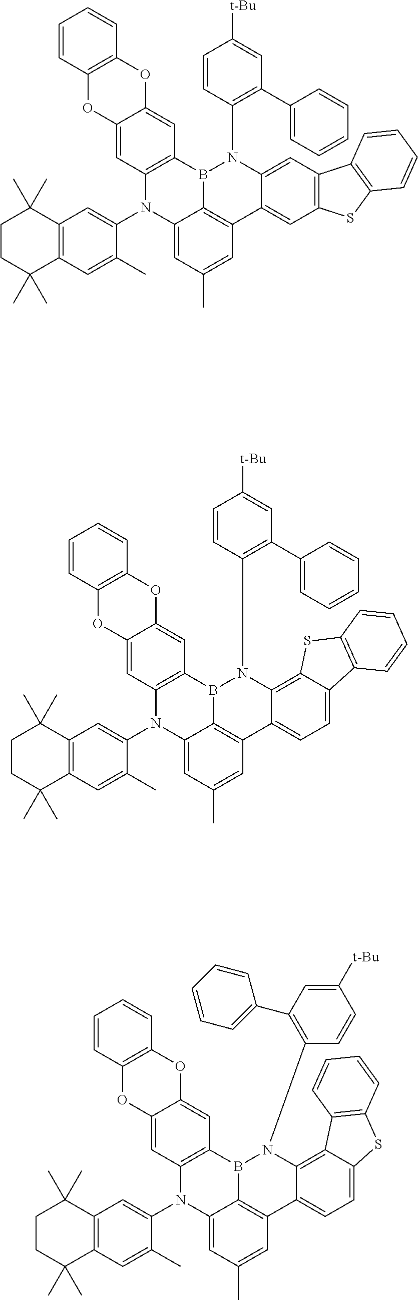 [SMILES: Cc1cc2c3c(c1)N(c1cc4c(cc1C)C(C)(C)CCC4(C)C)c1cc4c(cc1B3N(c1ccc(C(C)(C)C)cc1-c1ccccc1)c1cc3c(cc1-2)sc1ccccc13)Oc1ccccc1O4 ; Cc1cc2c3c(c1)N(c1cc4c(cc1C)C(C)(C)CCC4(C)C)c1cc4c(cc1B3N(c1ccc(C(C)(C)C)cc1-c1ccccc1)c1c-2ccc2c1sc1ccccc12)Oc1ccccc1O4 ; Cc1cc2c3c(c1)N(c1cc4c(cc1C)C(C)(C)CCC4(C)C)c1cc4c(cc1B3N(c1ccc(C(C)(C)C)cc1-c1ccccc1)c1c-2ccc2sc3ccccc3c12)Oc1ccccc1O4] 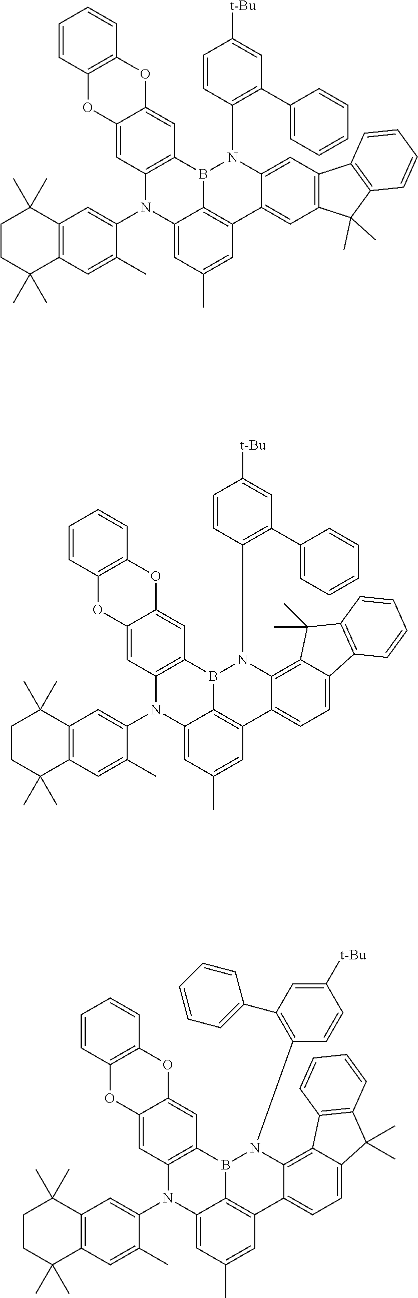 [SMILES: Cc1cc2c3c(c1)N(c1cc4c(cc1C)C(C)(C)CCC4(C)C)c1cc4c(cc1B3N(c1ccc(C(C)(C)C)cc1-c1ccccc1)c1cc3c(cc1-2)C(C)(C)c1ccccc1-3)Oc1ccccc1O4 ; Cc1cc2c3c(c1)N(c1cc4c(cc1C)C(C)(C)CCC4(C)C)c1cc4c(cc1B3N(c1ccc(C(C)(C)C)cc1-c1ccccc1)c1c-2ccc2c1C(C)(C)c1ccccc1-2)Oc1ccccc1O4 ; Cc1cc2c3c(c1)N(c1cc4c(cc1C)C(C)(C)CCC4(C)C)c1cc4c(cc1B3N(c1ccc(C(C)(C)C)cc1-c1ccccc1)c1c-2ccc2c1-c1ccccc1C2(C)C)Oc1ccccc1O4] 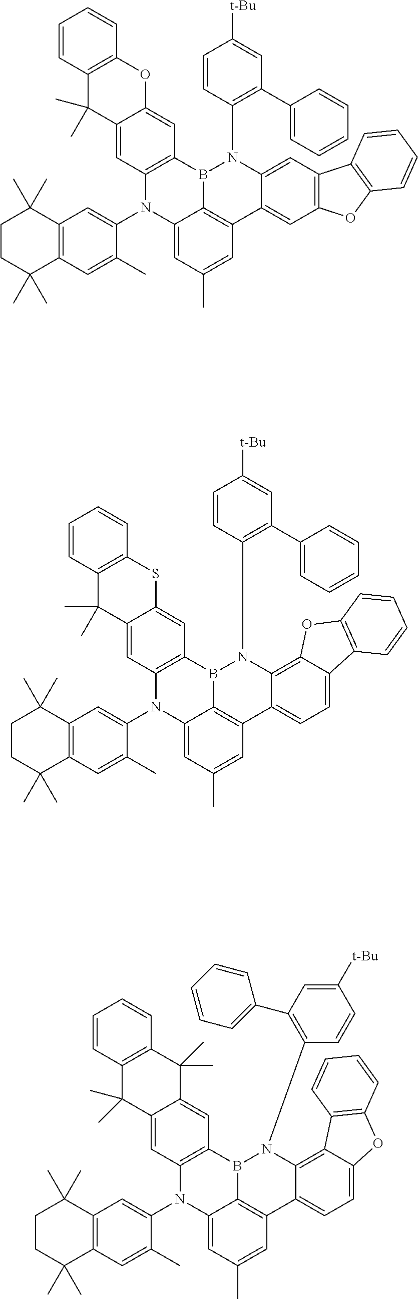 [SMILES: Cc1cc2c3c(c1)N(c1cc4c(cc1C)C(C)(C)CCC4(C)C)c1cc4c(cc1B3N(c1ccc(C(C)(C)C)cc1-c1ccccc1)c1cc3c(cc1-2)oc1ccccc13)Oc1ccccc1C4(C)C ; Cc1cc2c3c(c1)N(c1cc4c(cc1C)C(C)(C)CCC4(C)C)c1cc4c(cc1B3N(c1ccc(C(C)(C)C)cc1-c1ccccc1)c1c-2ccc2c1oc1ccccc12)Sc1ccccc1C4(C)C ; Cc1cc2c3c(c1)N(c1cc4c(cc1C)C(C)(C)CCC4(C)C)c1cc4c(cc1B3N(c1ccc(C(C)(C)C)cc1-c1ccccc1)c1c-2ccc2oc3ccccc3c12)C(C)(C)c1ccccc1C4(C)C] 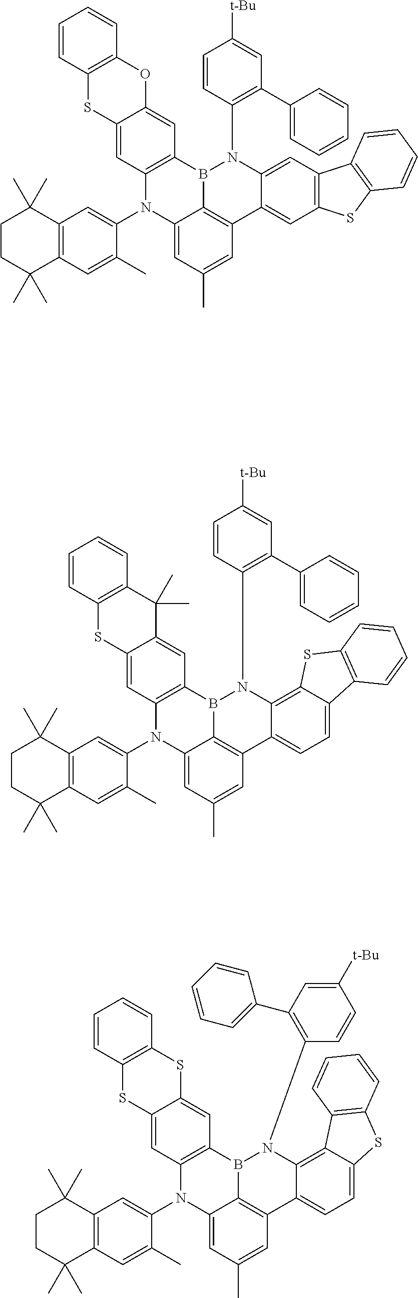 [SMILES: Cc1cc2c3c(c1)N(c1cc4c(cc1C)C(C)(C)CCC4(C)C)c1cc4c(cc1B3N(c1ccc(C(C)(C)C)cc1-c1ccccc1)c1cc3c(cc1-2)sc1ccccc13)Oc1ccccc1S4 ; Cc1cc2c3c(c1)N(c1cc4c(cc1C)C(C)(C)CCC4(C)C)c1cc4c(cc1B3N(c1ccc(C(C)(C)C)cc1-c1ccccc1)c1c-2ccc2c1sc1ccccc12)C(C)(C)c1ccccc1S4 ; Cc1cc2c3c(c1)N(c1cc4c(cc1C)C(C)(C)CCC4(C)C)c1cc4c(cc1B3N(c1ccc(C(C)(C)C)cc1-c1ccccc1)c1c-2ccc2sc3ccccc3c12)Sc1ccccc1S4] 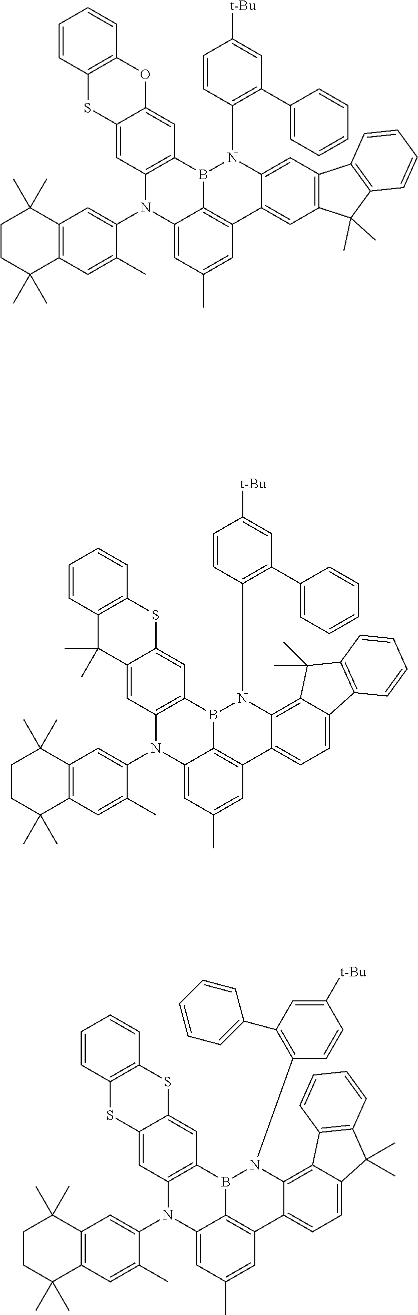 [SMILES: Cc1cc2c3c(c1)N(c1cc4c(cc1C)C(C)(C)CCC4(C)C)c1cc4c(cc1B3N(c1ccc(C(C)(C)C)cc1-c1ccccc1)c1cc3c(cc1-2)C(C)(C)c1ccccc1-3)Oc1ccccc1S4 ; Cc1cc2c3c(c1)N(c1cc4c(cc1C)C(C)(C)CCC4(C)C)c1cc4c(cc1B3N(c1ccc(C(C)(C)C)cc1-c1ccccc1)c1c-2ccc2c1C(C)(C)c1ccccc1-2)Sc1ccccc1C4(C)C ; Cc1cc2c3c(c1)N(c1cc4c(cc1C)C(C)(C)CCC4(C)C)c1cc4c(cc1B3N(c1ccc(C(C)(C)C)cc1-c1ccccc1)c1c-2ccc2c1-c1ccccc1C2(C)C)Sc1ccccc1S4] 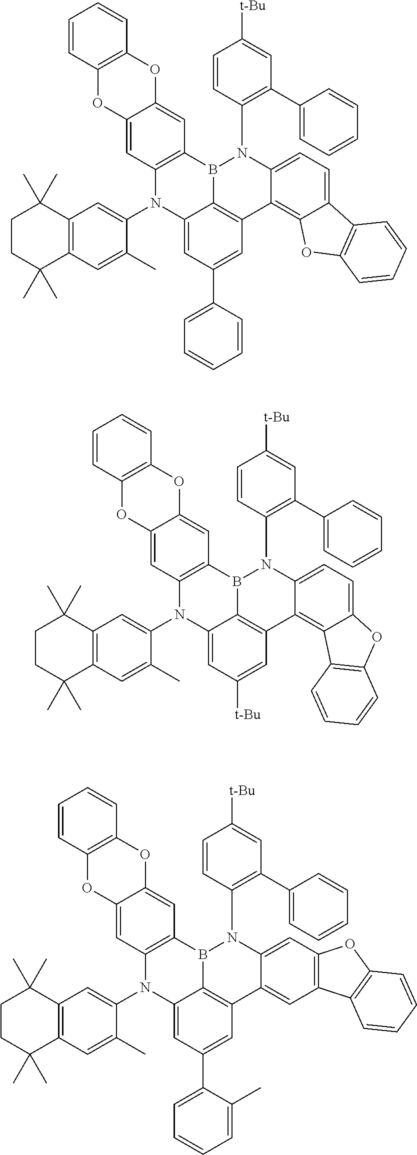 [SMILES: Cc1cc2c(cc1N1c3cc4c(cc3B3c5c(cc(-c6ccccc6)cc51)-c1c(ccc5c1oc1ccccc15)N3c1ccc(C(C)(C)C)cc1-c1ccccc1)Oc1ccccc1O4)C(C)(C)CCC2(C)C ; Cc1cc2c(cc1N1c3cc4c(cc3B3c5c(cc(C(C)(C)C)cc51)-c1c(ccc5oc6ccccc6c15)N3c1ccc(C(C)(C)C)cc1-c1ccccc1)Oc1ccccc1O4)C(C)(C)CCC2(C)C ; Cc1ccccc1-c1cc2c3c(c1)N(c1cc4c(cc1C)C(C)(C)CCC4(C)C)c1cc4c(cc1B3N(c1ccc(C(C)(C)C)cc1-c1ccccc1)c1cc3oc5ccccc5c3cc1-2)Oc1ccccc1O4] 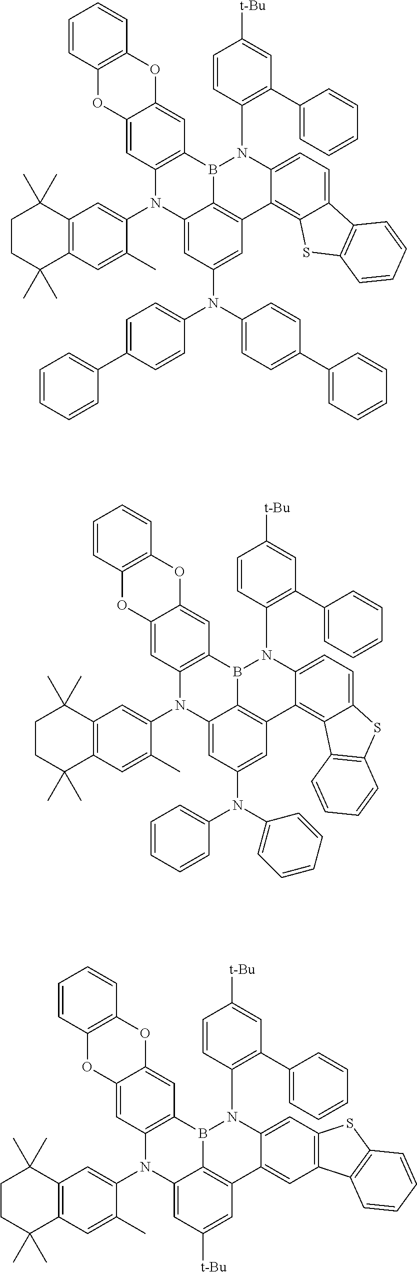 [SMILES: Cc1cc2c(cc1N1c3cc4c(cc3B3c5c(cc(N(c6ccc(-c7ccccc7)cc6)c6ccc(-c7ccccc7)cc6)cc51)-c1c(ccc5c1sc1ccccc15)N3c1ccc(C(C)(C)C)cc1-c1ccccc1)Oc1ccccc1O4)C(C)(C)CCC2(C)C ; Cc1cc2c(cc1N1c3cc4c(cc3B3c5c(cc(N(c6ccccc6)c6ccccc6)cc51)-c1c(ccc5sc6ccccc6c15)N3c1ccc(C(C)(C)C)cc1-c1ccccc1)Oc1ccccc1O4)C(C)(C)CCC2(C)C ; Cc1cc2c(cc1N1c3cc4c(cc3B3c5c(cc(C(C)(C)C)cc51)-c1cc5c(cc1N3c1ccc(C(C)(C)C)cc1-c1ccccc1)sc1ccccc15)Oc1ccccc1O4)C(C)(C)CCC2(C)C] 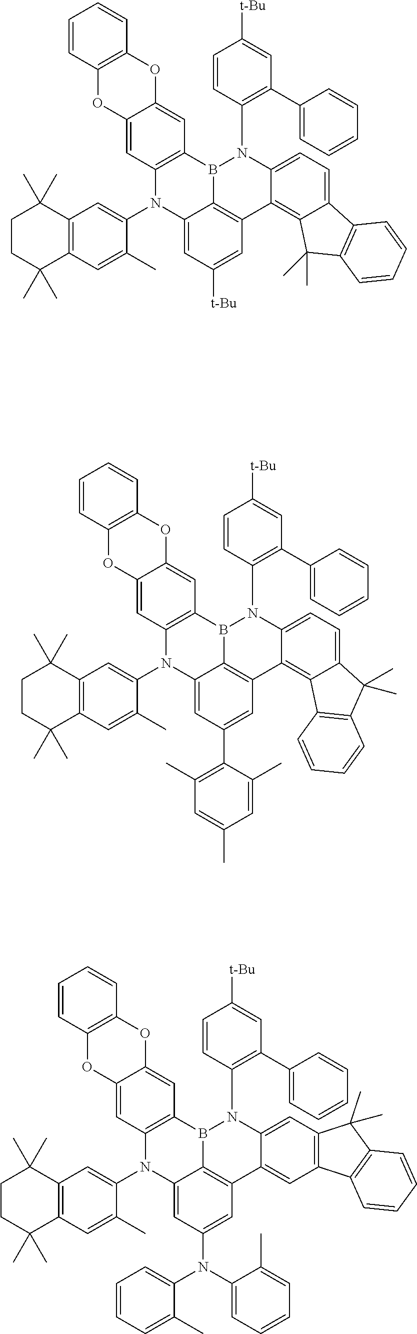 [SMILES: Cc1cc2c(cc1N1c3cc4c(cc3B3c5c(cc(C(C)(C)C)cc51)-c1c(ccc5c1C(C)(C)c1ccccc1-5)N3c1ccc(C(C)(C)C)cc1-c1ccccc1)Oc1ccccc1O4)C(C)(C)CCC2(C)C ; Cc1cc(C)c(-c2cc3c4c(c2)N(c2cc5c(cc2C)C(C)(C)CCC5(C)C)c2cc5c(cc2B4N(c2ccc(C(C)(C)C)cc2-c2ccccc2)c2ccc4c(c2-3)-c2ccccc2C4(C)C)Oc2ccccc2O5)c(C)c1 ; Cc1ccccc1N(c1cc2c3c(c1)N(c1cc4c(cc1C)C(C)(C)CCC4(C)C)c1cc4c(cc1B3N(c1ccc(C(C)(C)C)cc1-c1ccccc1)c1cc3c(cc1-2)-c1ccccc1C3(C)C)Oc1ccccc1O4)c1ccccc1C] 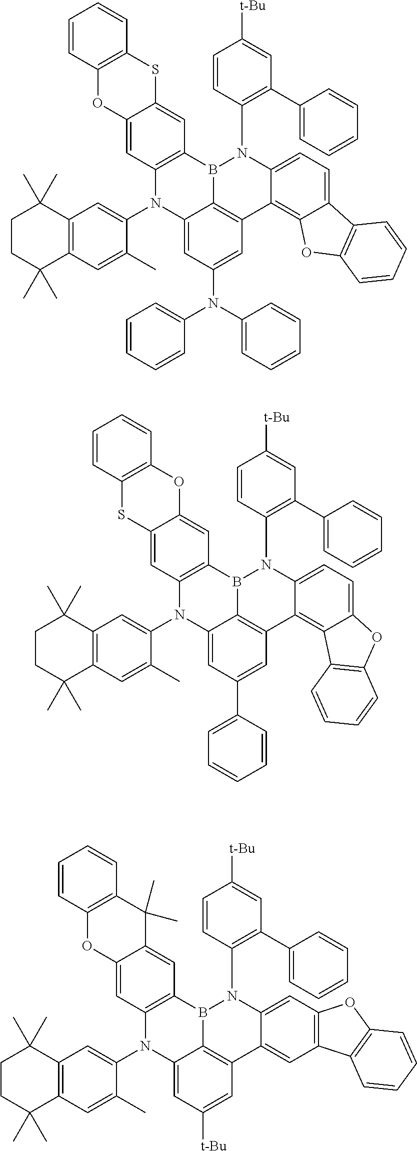 [SMILES: Cc1cc2c(cc1N1c3cc4c(cc3B3c5c(cc(N(c6ccccc6)c6ccccc6)cc51)-c1c(ccc5c1oc1ccccc15)N3c1ccc(C(C)(C)C)cc1-c1ccccc1)Sc1ccccc1O4)C(C)(C)CCC2(C)C ; Cc1cc2c(cc1N1c3cc4c(cc3B3c5c(cc(-c6ccccc6)cc51)-c1c(ccc5oc6ccccc6c15)N3c1ccc(C(C)(C)C)cc1-c1ccccc1)Oc1ccccc1S4)C(C)(C)CCC2(C)C ; Cc1cc2c(cc1N1c3cc4c(cc3B3c5c(cc(C(C)(C)C)cc51)-c1cc5c(cc1N3c1ccc(C(C)(C)C)cc1-c1ccccc1)oc1ccccc15)C(C)(C)c1ccccc1O4)C(C)(C)CCC2(C)C] 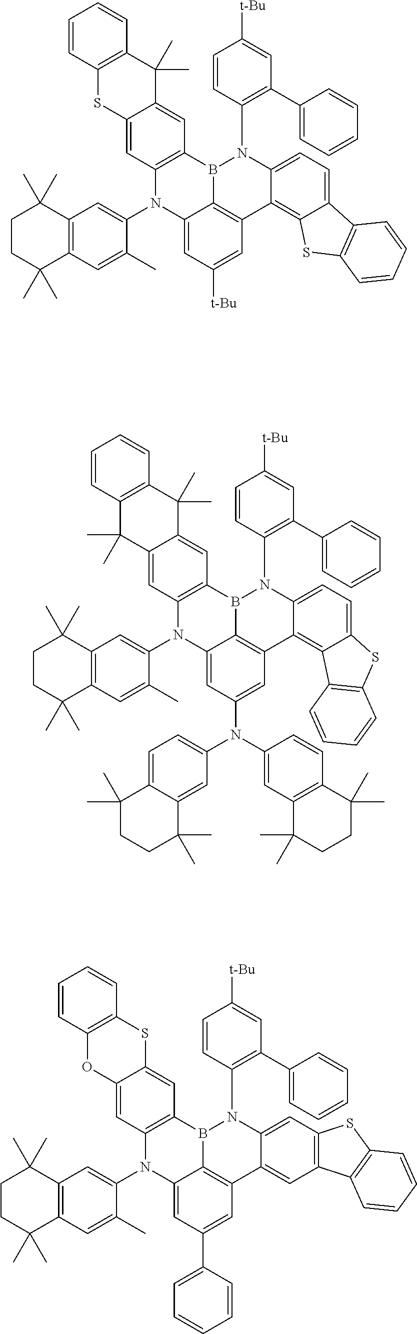 [SMILES: Cc1cc2c(cc1N1c3cc4c(cc3B3c5c(cc(C(C)(C)C)cc51)-c1c(ccc5c1sc1ccccc15)N3c1ccc(C(C)(C)C)cc1-c1ccccc1)C(C)(C)c1ccccc1S4)C(C)(C)CCC2(C)C ; Cc1cc2c(cc1N1c3cc4c(cc3B3c5c(cc(N(c6ccc7c(c6)C(C)(C)CCC7(C)C)c6ccc7c(c6)C(C)(C)CCC7(C)C)cc51)-c1c(ccc5sc6ccccc6c15)N3c1ccc(C(C)(C)C)cc1-c1ccccc1)C(C)(C)c1ccccc1C4(C)C)C(C)(C)CCC2(C)C ; Cc1cc2c(cc1N1c3cc4c(cc3B3c5c(cc(-c6ccccc6)cc51)-c1cc5c(cc1N3c1ccc(C(C)(C)C)cc1-c1ccccc1)sc1ccccc15)Sc1ccccc1O4)C(C)(C)CCC2(C)C] 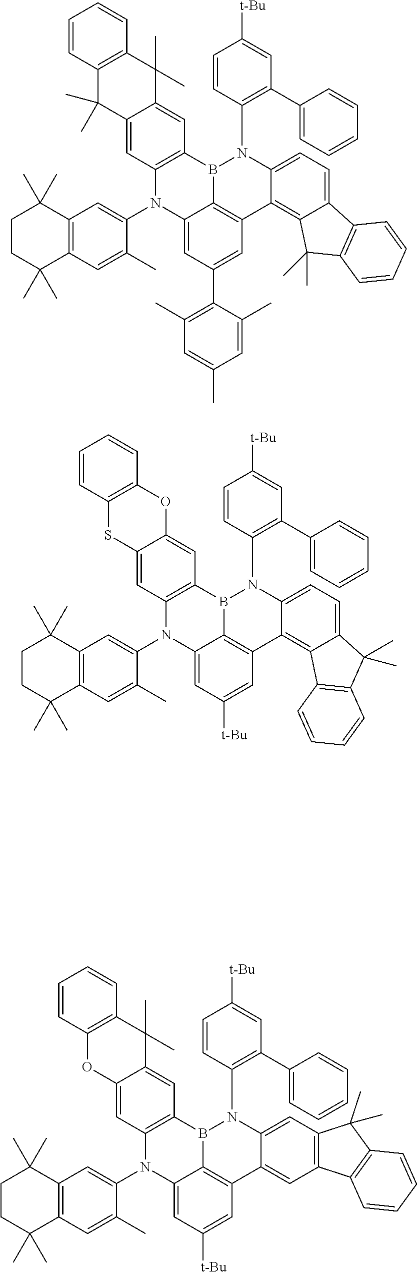 [SMILES: Cc1cc(C)c(-c2cc3c4c(c2)N(c2cc5c(cc2C)C(C)(C)CCC5(C)C)c2cc5c(cc2B4N(c2ccc(C(C)(C)C)cc2-c2ccccc2)c2ccc4c(c2-3)C(C)(C)c2ccccc2-4)C(C)(C)c2ccccc2C5(C)C)c(C)c1 ; Cc1cc2c(cc1N1c3cc4c(cc3B3c5c(cc(C(C)(C)C)cc51)-c1c(ccc5c1-c1ccccc1C5(C)C)N3c1ccc(C(C)(C)C)cc1-c1ccccc1)Oc1ccccc1S4)C(C)(C)CCC2(C)C ; Cc1cc2c(cc1N1c3cc4c(cc3B3c5c(cc(C(C)(C)C)cc51)-c1cc5c(cc1N3c1ccc(C(C)(C)C)cc1-c1ccccc1)C(C)(C)c1ccccc1-5)C(C)(C)c1ccccc1O4)C(C)(C)CCC2(C)C] 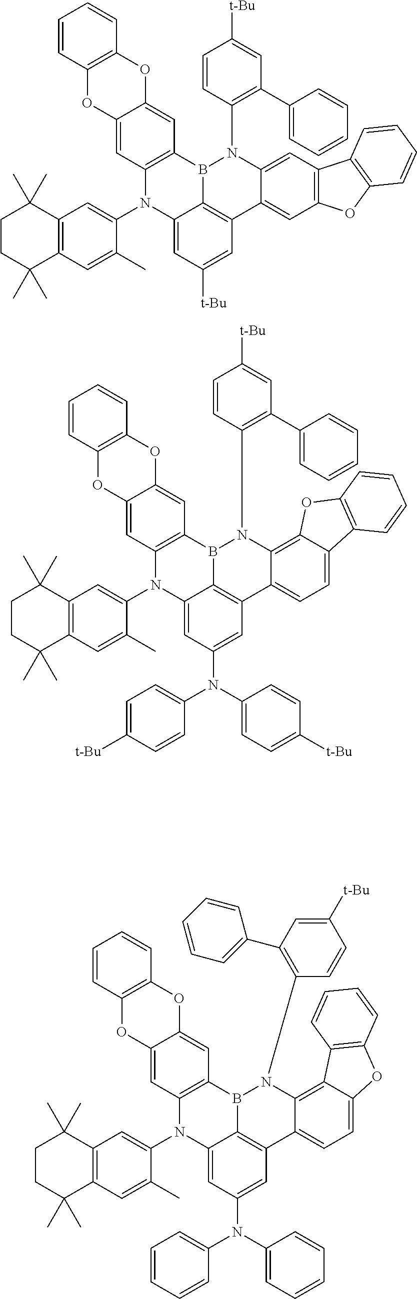 [SMILES: Cc1cc2c(cc1N1c3cc4c(cc3B3c5c(cc(C(C)(C)C)cc51)-c1cc5oc6ccccc6c5cc1N3c1ccc(C(C)(C)C)cc1-c1ccccc1)Oc1ccccc1O4)C(C)(C)CCC2(C)C ; Cc1cc2c(cc1N1c3cc4c(cc3B3c5c(cc(N(c6ccc(C(C)(C)C)cc6)c6ccc(C(C)(C)C)cc6)cc51)-c1ccc5c(oc6ccccc65)c1N3c1ccc(C(C)(C)C)cc1-c1ccccc1)Oc1ccccc1O4)C(C)(C)CCC2(C)C ; Cc1cc2c(cc1N1c3cc4c(cc3B3c5c(cc(N(c6ccccc6)c6ccccc6)cc51)-c1ccc5oc6ccccc6c5c1N3c1ccc(C(C)(C)C)cc1-c1ccccc1)Oc1ccccc1O4)C(C)(C)CCC2(C)C] 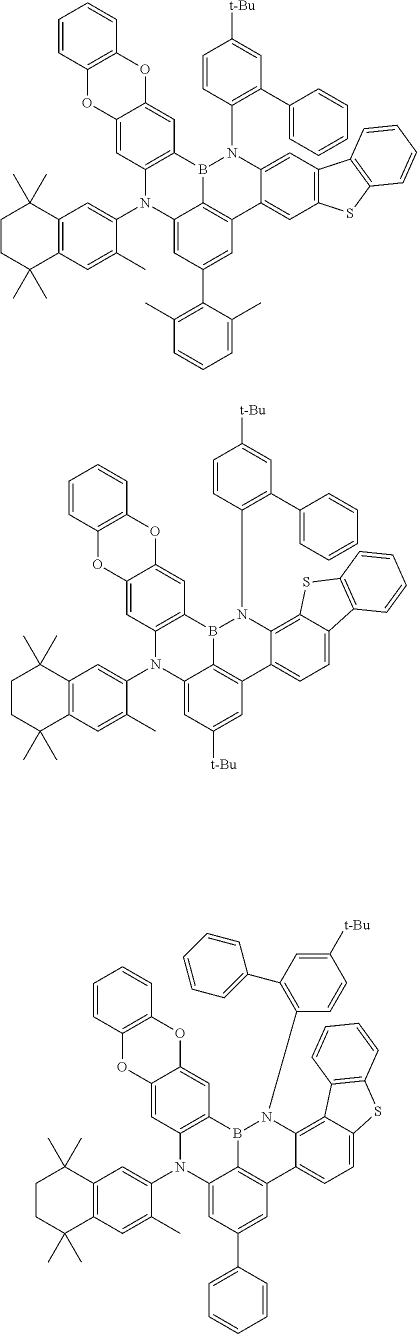 [SMILES: Cc1cc2c(cc1N1c3cc4c(cc3B3c5c(cc(-c6c(C)cccc6C)cc51)-c1cc5sc6ccccc6c5cc1N3c1ccc(C(C)(C)C)cc1-c1ccccc1)Oc1ccccc1O4)C(C)(C)CCC2(C)C ; Cc1cc2c(cc1N1c3cc4c(cc3B3c5c(cc(C(C)(C)C)cc51)-c1ccc5c(sc6ccccc65)c1N3c1ccc(C(C)(C)C)cc1-c1ccccc1)Oc1ccccc1O4)C(C)(C)CCC2(C)C ; Cc1cc2c(cc1N1c3cc4c(cc3B3c5c(cc(-c6ccccc6)cc51)-c1ccc5sc6ccccc6c5c1N3c1ccc(C(C)(C)C)cc1-c1ccccc1)Oc1ccccc1O4)C(C)(C)CCC2(C)C] 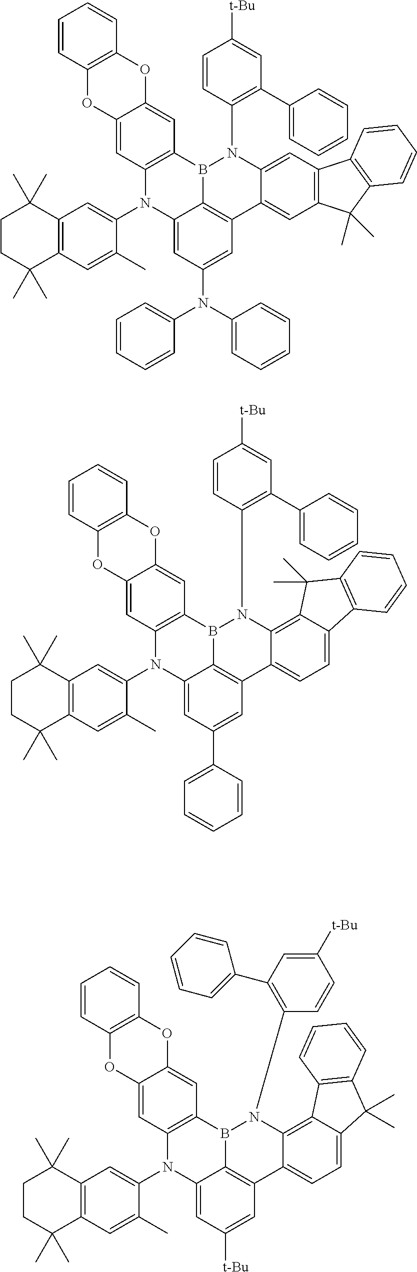 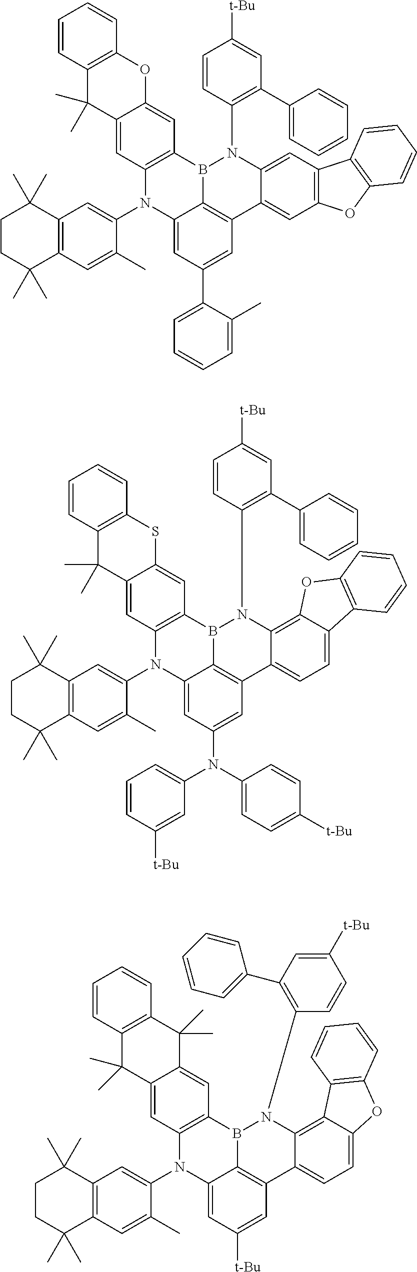 [SMILES: Cc1ccccc1-c1cc2c3c(c1)N(c1cc4c(cc1C)C(C)(C)CCC4(C)C)c1cc4c(cc1B3N(c1ccc(C(C)(C)C)cc1-c1ccccc1)c1cc3c(cc1-2)oc1ccccc13)Oc1ccccc1C4(C)C ; Cc1cc2c(cc1N1c3cc4c(cc3B3c5c(cc(N(c6ccc(C(C)(C)C)cc6)c6cccc(C(C)(C)C)c6)cc51)-c1ccc5c(oc6ccccc65)c1N3c1ccc(C(C)(C)C)cc1-c1ccccc1)Sc1ccccc1C4(C)C)C(C)(C)CCC2(C)C ; Cc1cc2c(cc1N1c3cc4c(cc3B3c5c(cc(C(C)(C)C)cc51)-c1ccc5oc6ccccc6c5c1N3c1ccc(C(C)(C)C)cc1-c1ccccc1)C(C)(C)c1ccccc1C4(C)C)C(C)(C)CCC2(C)C] 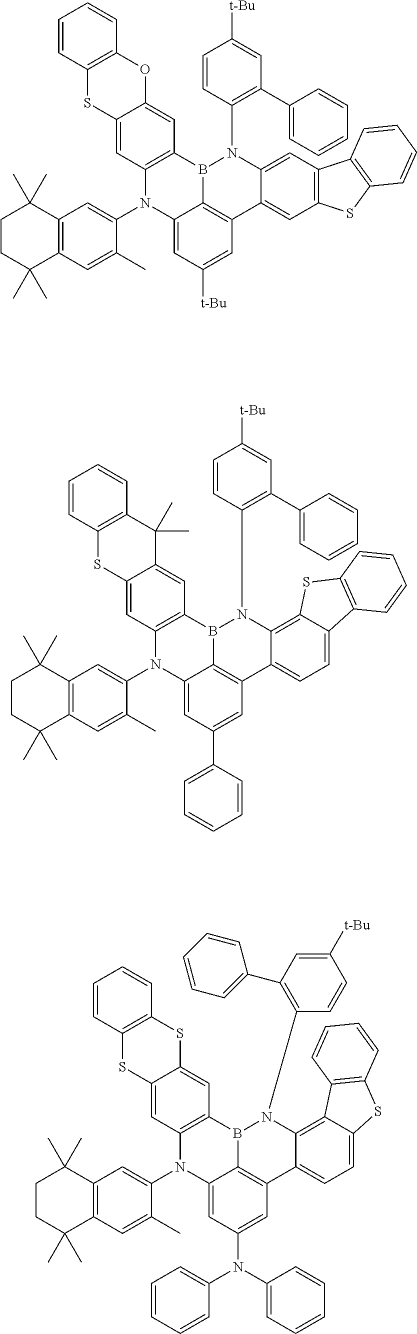 [SMILES: Cc1cc2c(cc1N1c3cc4c(cc3B3c5c(cc(C(C)(C)C)cc51)-c1cc5sc6ccccc6c5cc1N3c1ccc(C(C)(C)C)cc1-c1ccccc1)Oc1ccccc1S4)C(C)(C)CCC2(C)C ; Cc1cc2c(cc1N1c3cc4c(cc3B3c5c(cc(-c6ccccc6)cc51)-c1ccc5c(sc6ccccc65)c1N3c1ccc(C(C)(C)C)cc1-c1ccccc1)C(C)(C)c1ccccc1S4)C(C)(C)CCC2(C)C ; Cc1cc2c(cc1N1c3cc4c(cc3B3c5c(cc(N(c6ccccc6)c6ccccc6)cc51)-c1ccc5sc6ccccc6c5c1N3c1ccc(C(C)(C)C)cc1-c1ccccc1)Sc1ccccc1S4)C(C)(C)CCC2(C)C] 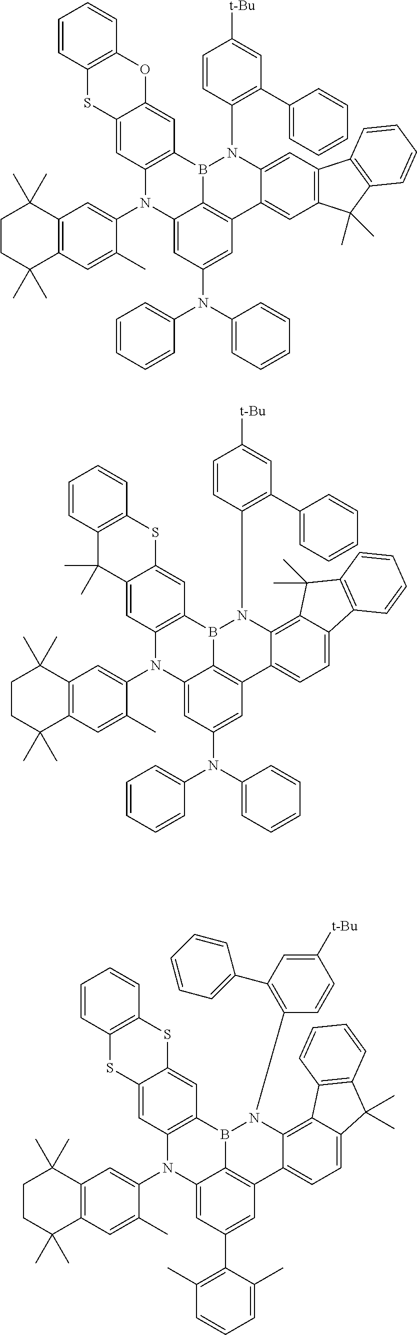 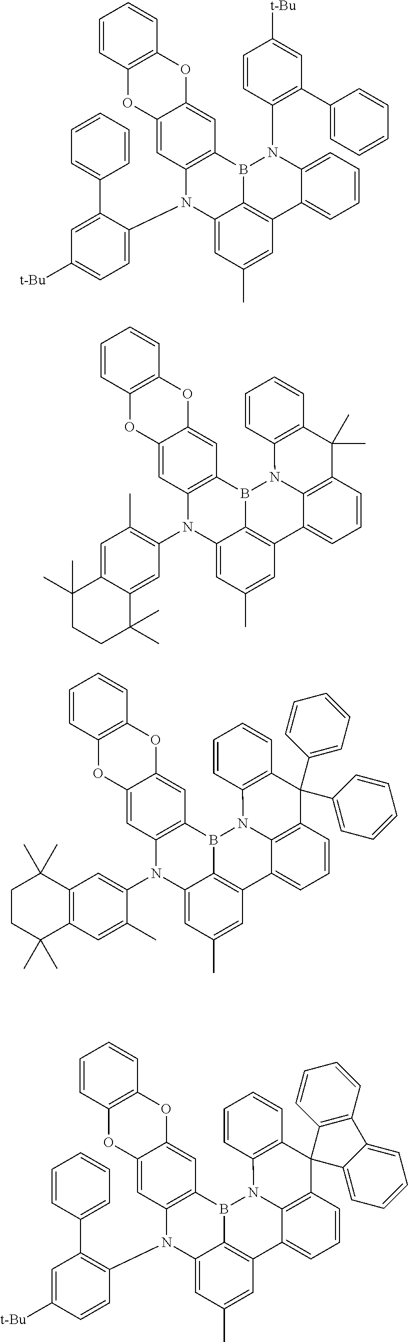 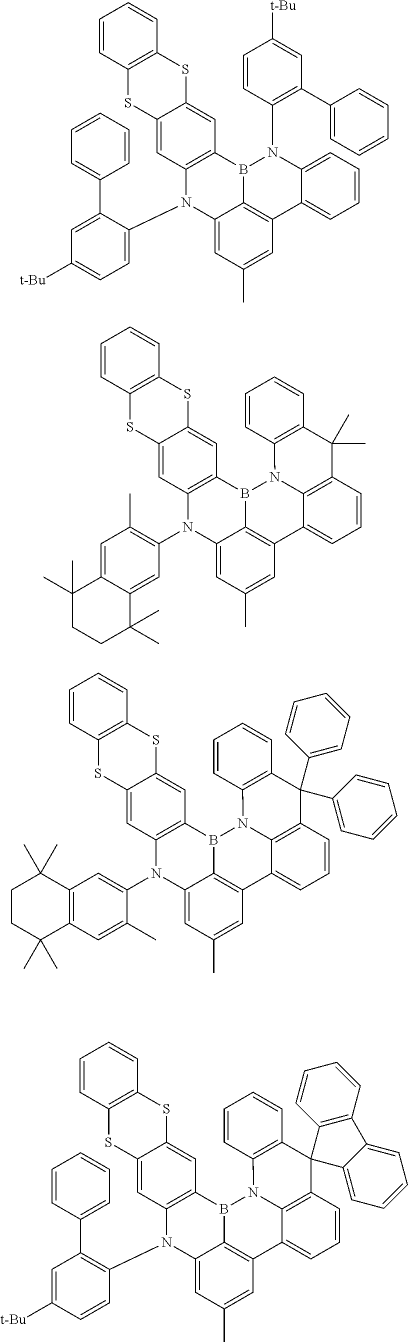 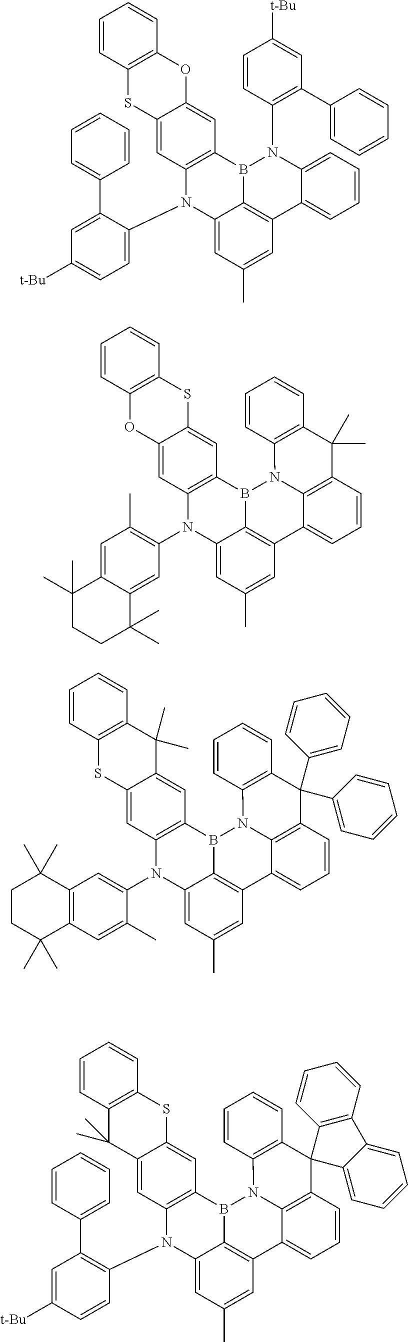 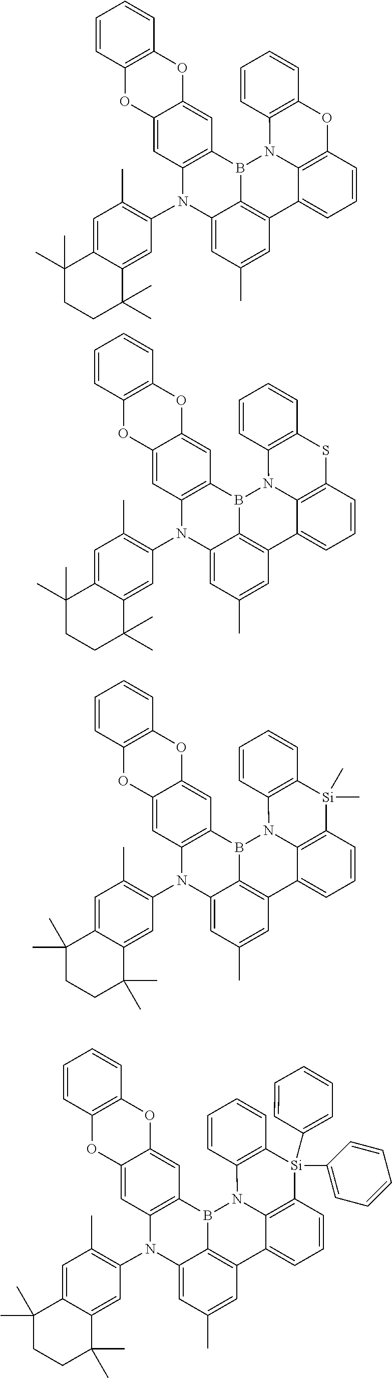 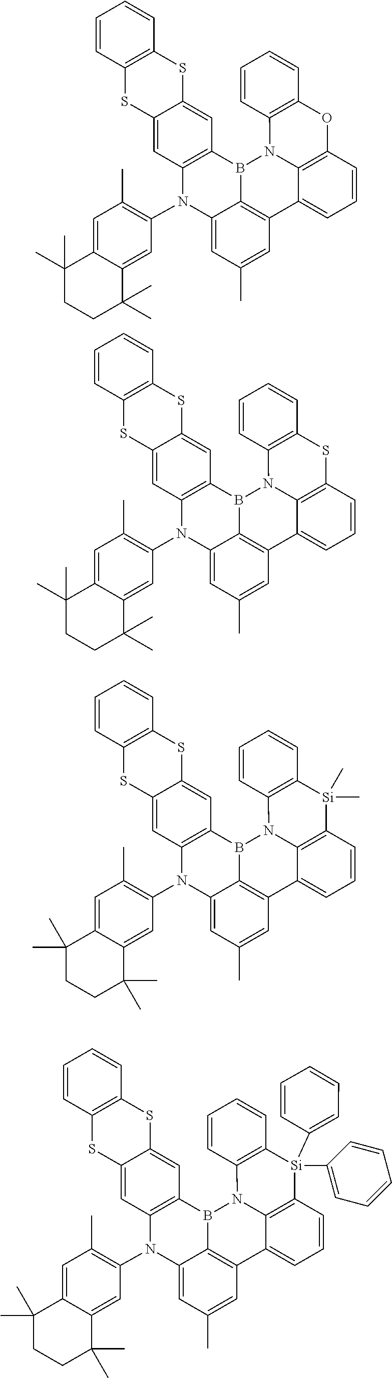 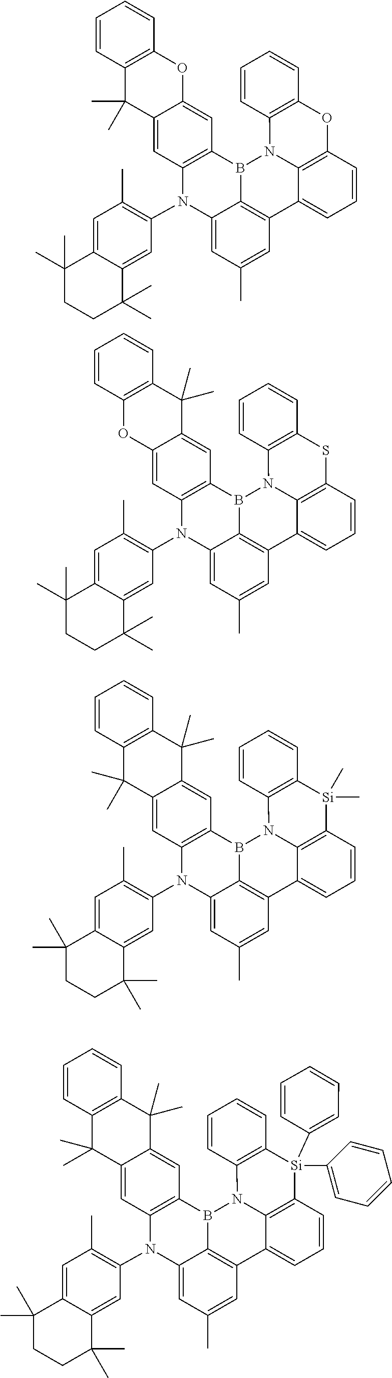 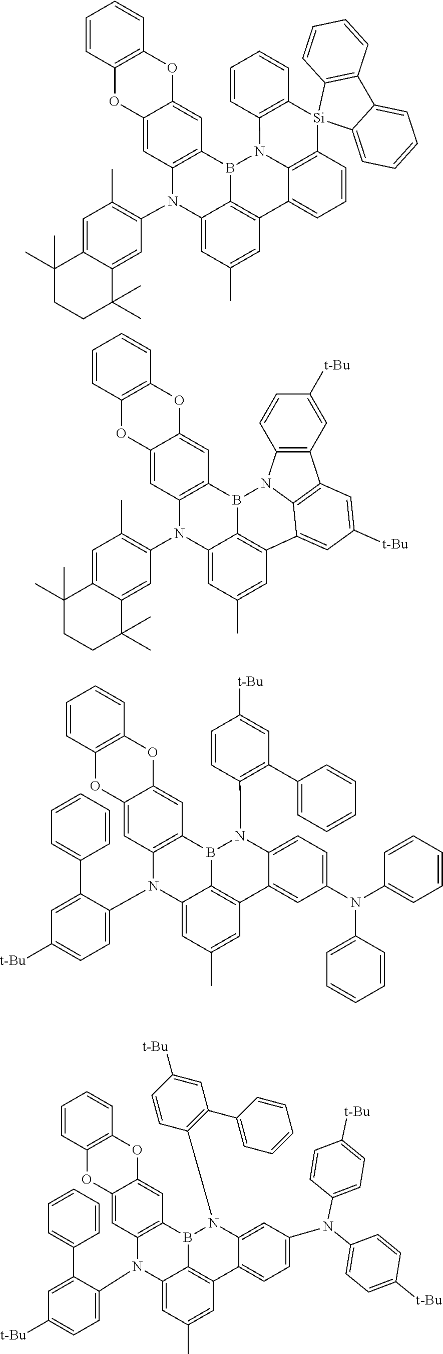 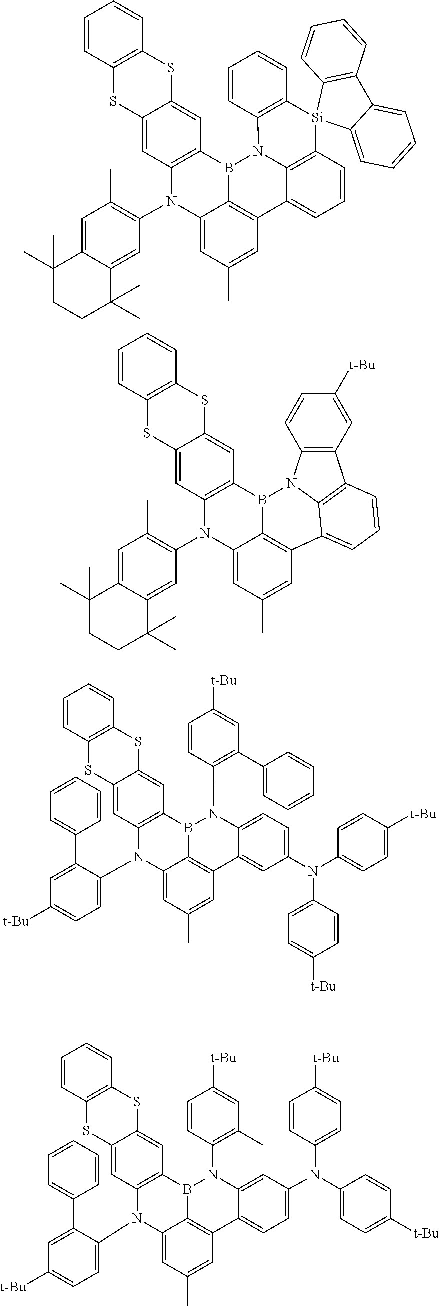 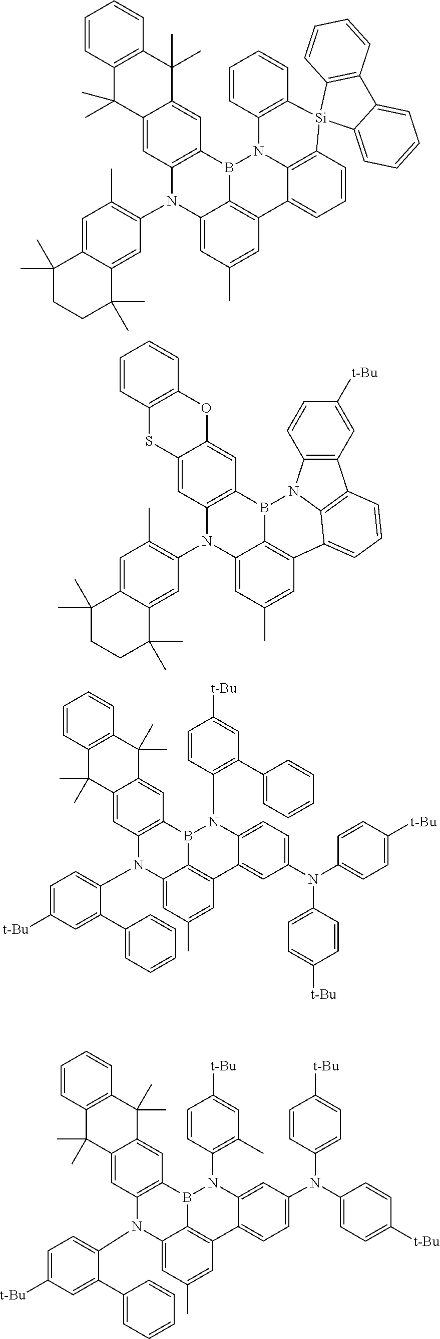 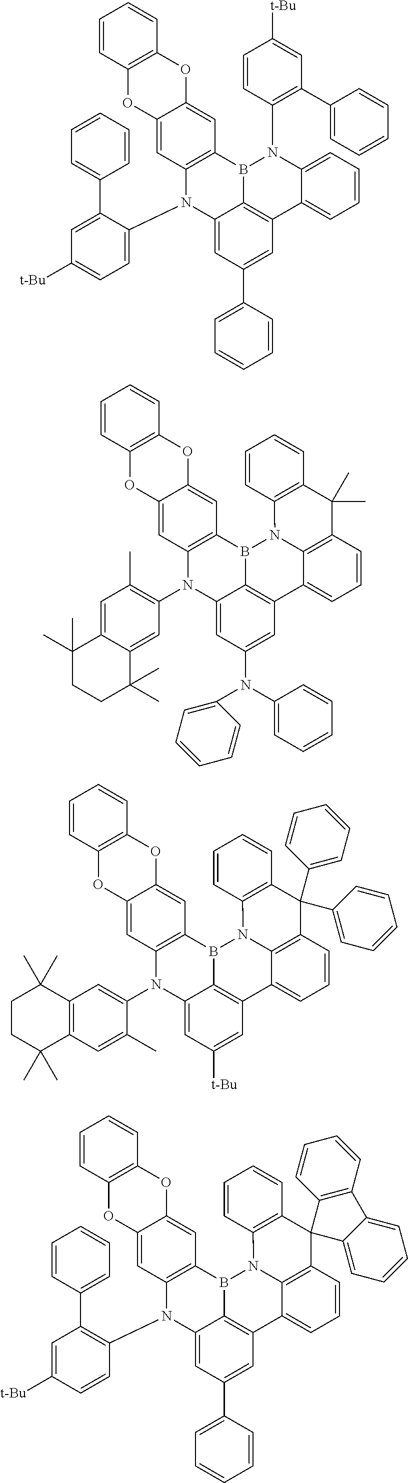 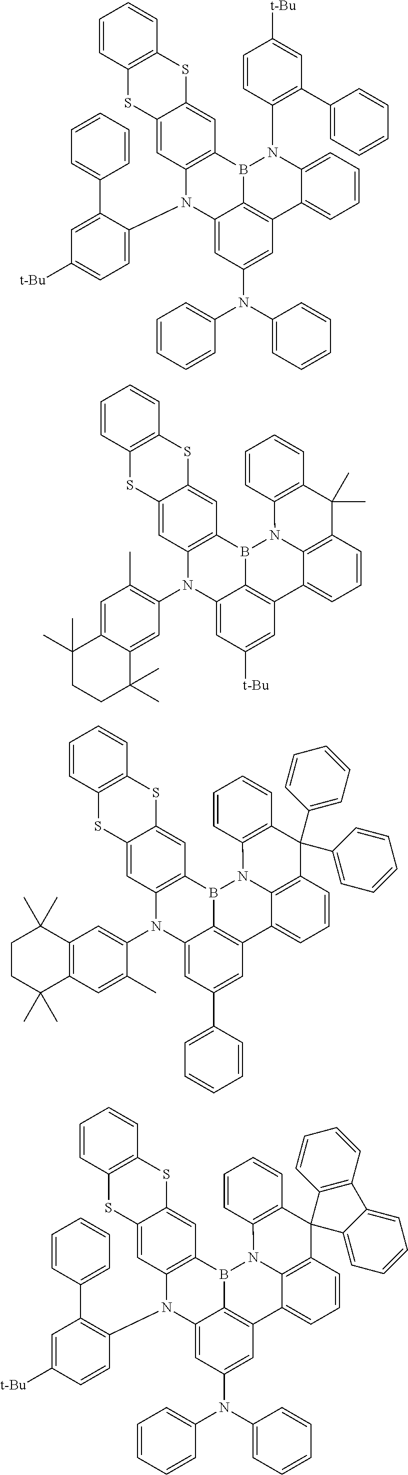 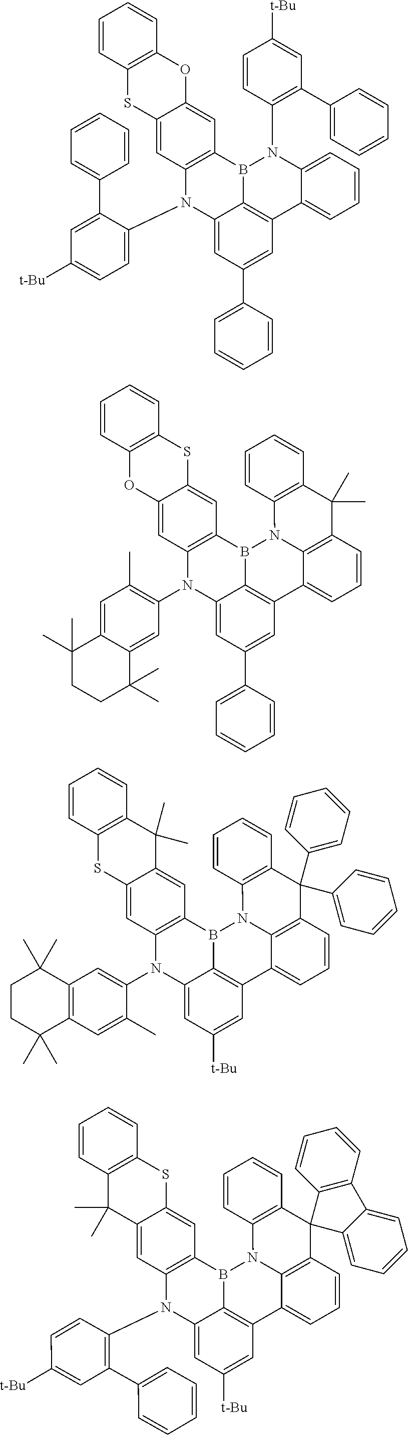 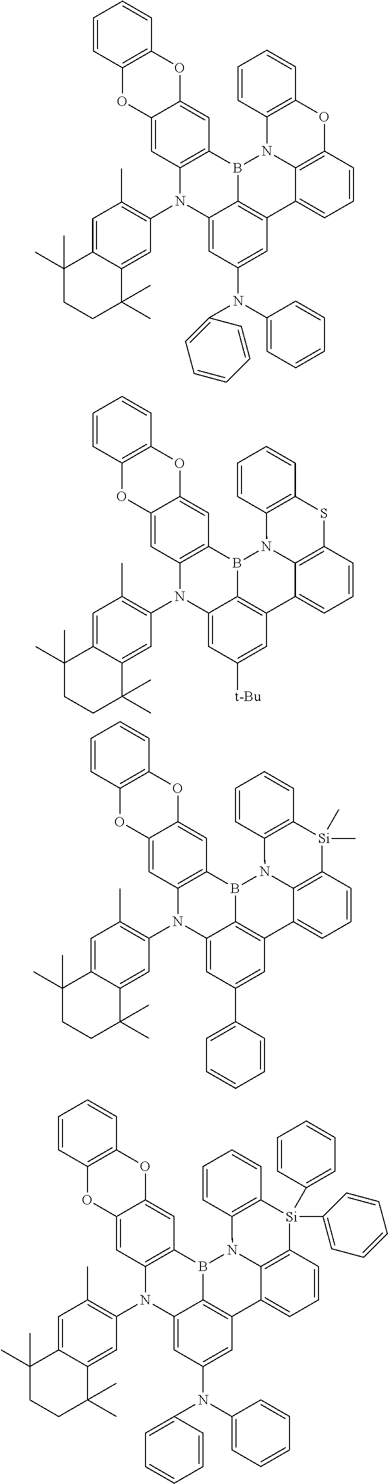 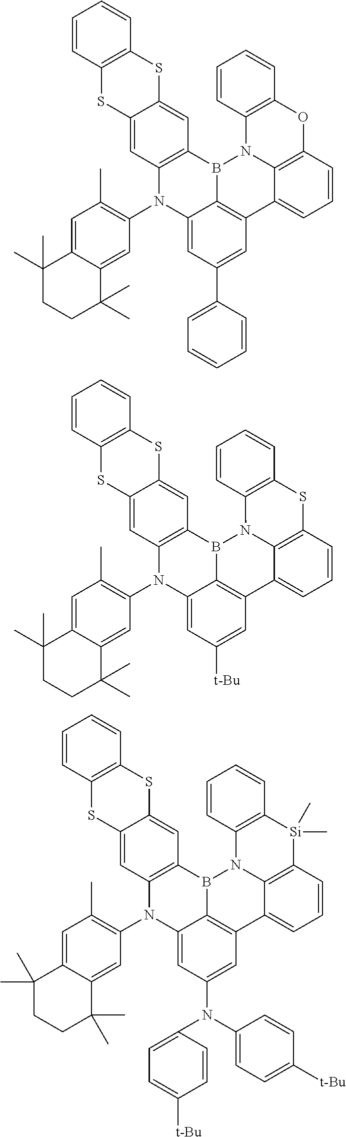 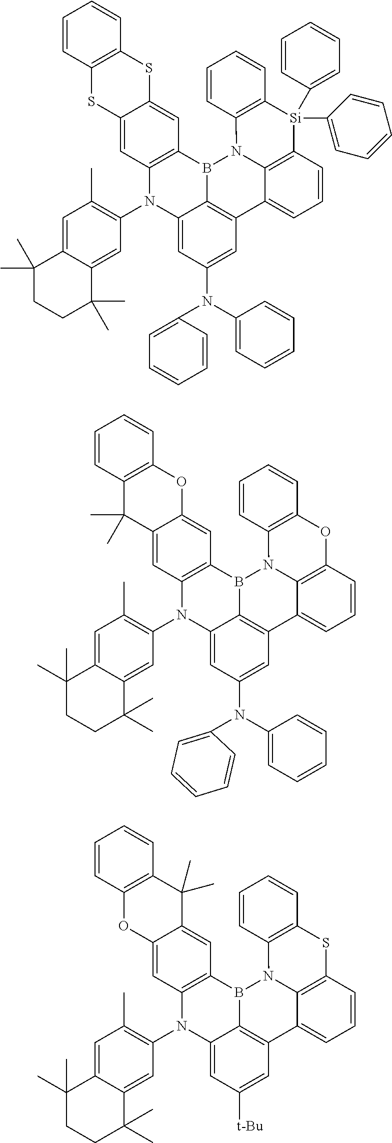 [SMILES: Cc1cc2c(cc1N1c3cc4c(cc3B3c5c(cc(N(c6ccccc6)c6ccccc6)cc51)-c1cccc5c1N3c1ccccc1[Si]5(c1ccccc1)c1ccccc1)Sc1ccccc1S4)C(C)(C)CCC2(C)C ; Cc1cc2c(cc1N1c3cc4c(cc3B3c5c(cc(N(c6ccccc6)c6ccccc6)cc51)-c1cccc5c1N3c1ccccc1O5)Oc1ccccc1C4(C)C)C(C)(C)CCC2(C)C ; Cc1cc2c(cc1N1c3cc4c(cc3B3c5c(cc(C(C)(C)C)cc51)-c1cccc5c1N3c1ccccc1S5)C(C)(C)c1ccccc1O4)C(C)(C)CCC2(C)C] 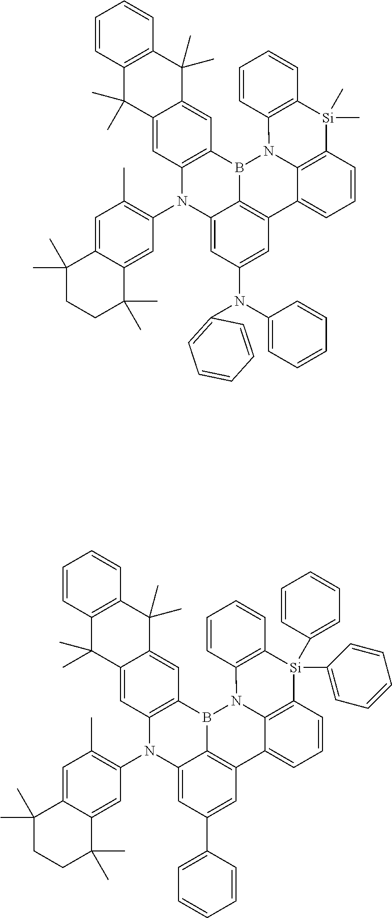 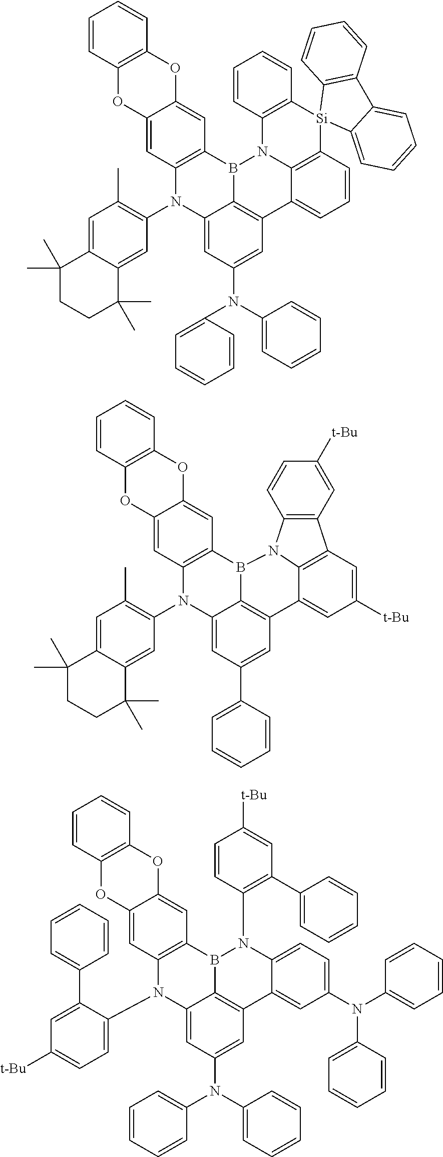 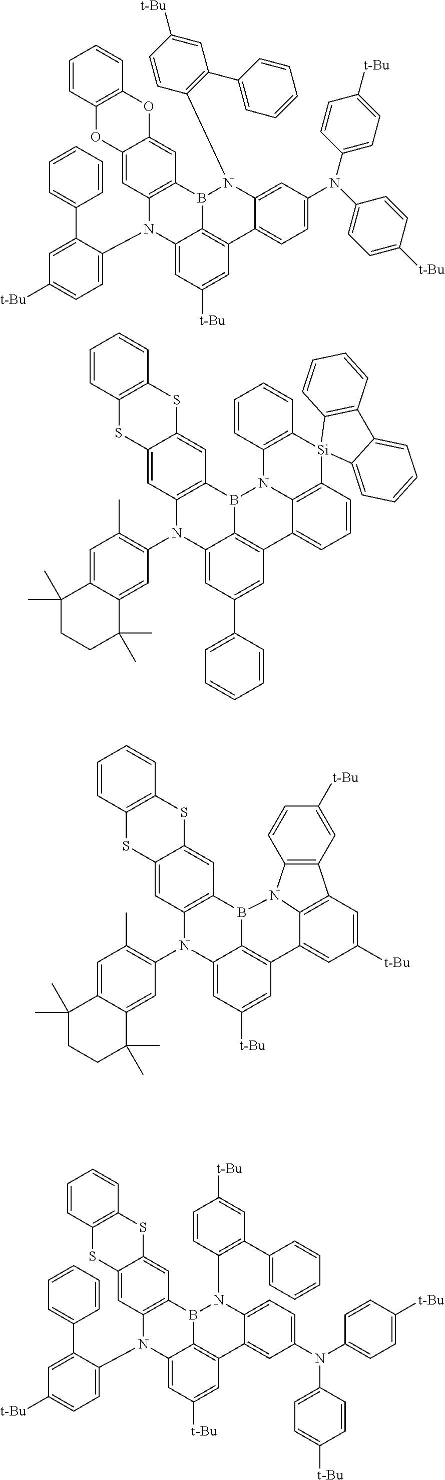 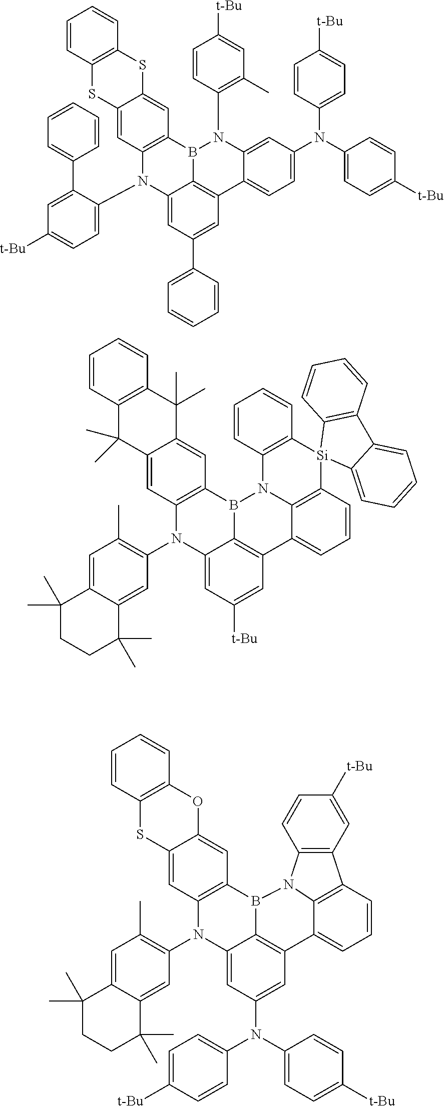 [SMILES: Cc1cc(C(C)(C)C)ccc1N1B2c3cc4c(cc3N(c3ccc(C(C)(C)C)cc3-c3ccccc3)c3cc(-c5ccccc5)cc(c32)-c2ccc(N(c3ccc(C(C)(C)C)cc3)c3ccc(C(C)(C)C)cc3)cc21)Sc1ccccc1S4 ; Cc1cc2c(cc1N1c3cc4c(cc3B3c5c(cc(C(C)(C)C)cc51)-c1cccc5c1N3c1ccccc1[Si]51c3ccccc3-c3ccccc31)C(C)(C)c1ccccc1C4(C)C)C(C)(C)CCC2(C)C ; Cc1cc2c(cc1N1c3cc4c(cc3B3c5c(cc(N(c6ccc(C(C)(C)C)cc6)c6ccc(C(C)(C)C)cc6)cc51)-c1cccc5c6cc(C(C)(C)C)ccc6n3c15)Oc1ccccc1S4)C(C)(C)CCC2(C)C] 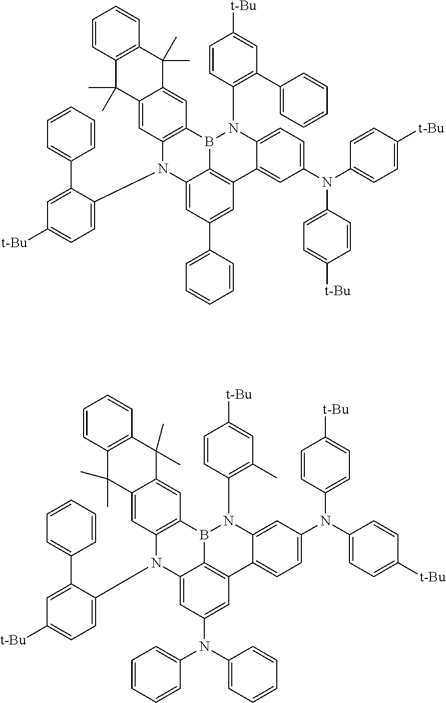 [SMILES: CC(C)(C)c1ccc(N(c2ccc(C(C)(C)C)cc2)c2ccc3c(c2)-c2cc(-c4ccccc4)cc4c2B(c2cc5c(cc2N4c2ccc(C(C)(C)C)cc2-c2ccccc2)C(C)(C)c2ccccc2C5(C)C)N3c2ccc(C(C)(C)C)cc2-c2ccccc2)cc1 ; Cc1cc(C(C)(C)C)ccc1N1B2c3cc4c(cc3N(c3ccc(C(C)(C)C)cc3-c3ccccc3)c3cc(N(c5ccccc5)c5ccccc5)cc(c32)-c2ccc(N(c3ccc(C(C)(C)C)cc3)c3ccc(C(C)(C)C)cc3)cc21)C(C)(C)c1ccccc1C4(C)C] 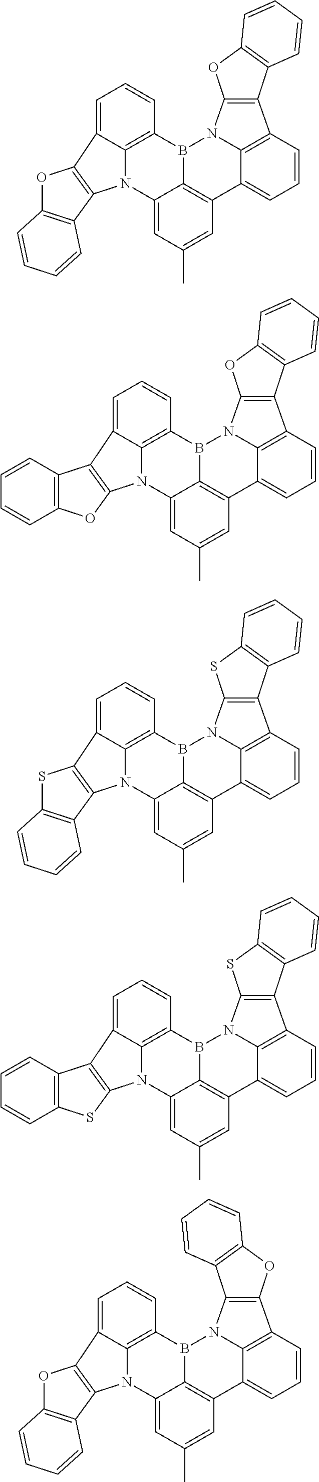 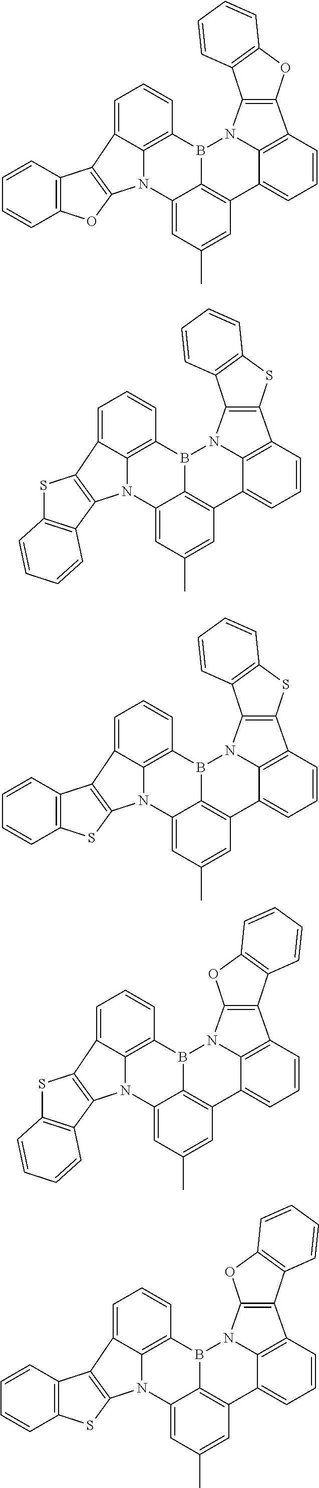 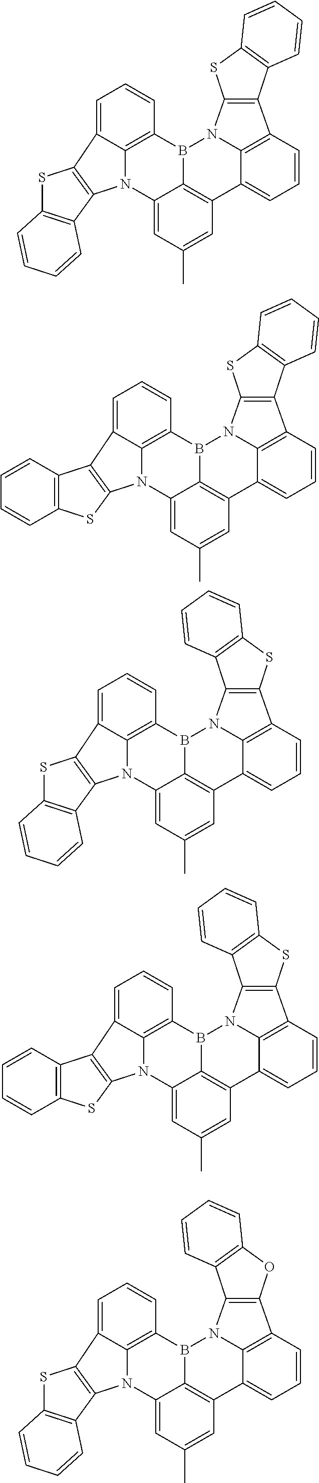 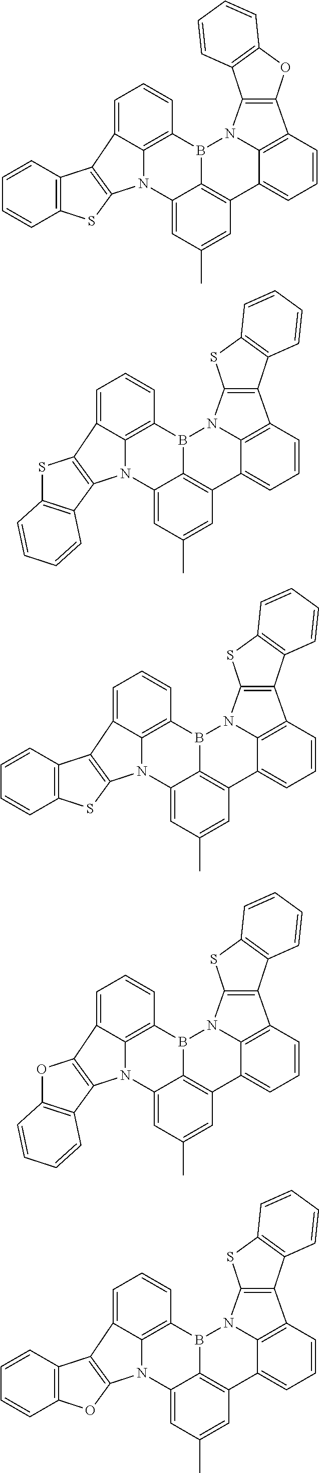 [SMILES: Cc1cc2c3c(c1)-n1c4sc5ccccc5c4c4cccc(c41)B3n1c3c-2cccc3c2oc3ccccc3c21 ; Cc1cc2c3c(c1)-n1c4c(cccc4c4sc5ccccc5c41)B3n1c3sc4ccccc4c3c3cccc-2c31 ; Cc1cc2c3c(c1)-n1c4sc5ccccc5c4c4cccc(c41)B3n1c3sc4ccccc4c3c3cccc-2c31 ; Cc1cc2c3c(c1)-n1c4c(cccc4c4oc5ccccc5c41)B3n1c3sc4ccccc4c3c3cccc-2c31 ; Cc1cc2c3c(c1)-n1c4oc5ccccc5c4c4cccc(c41)B3n1c3sc4ccccc4c3c3cccc-2c31] 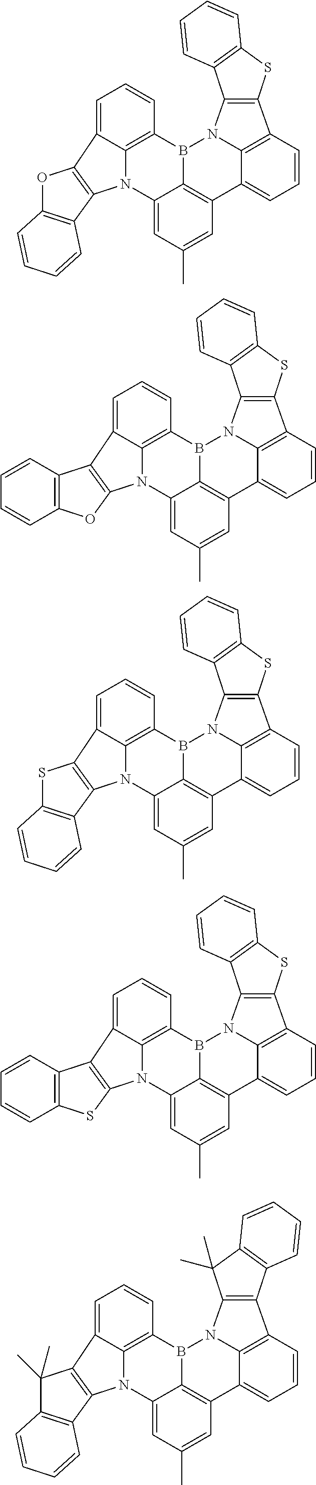 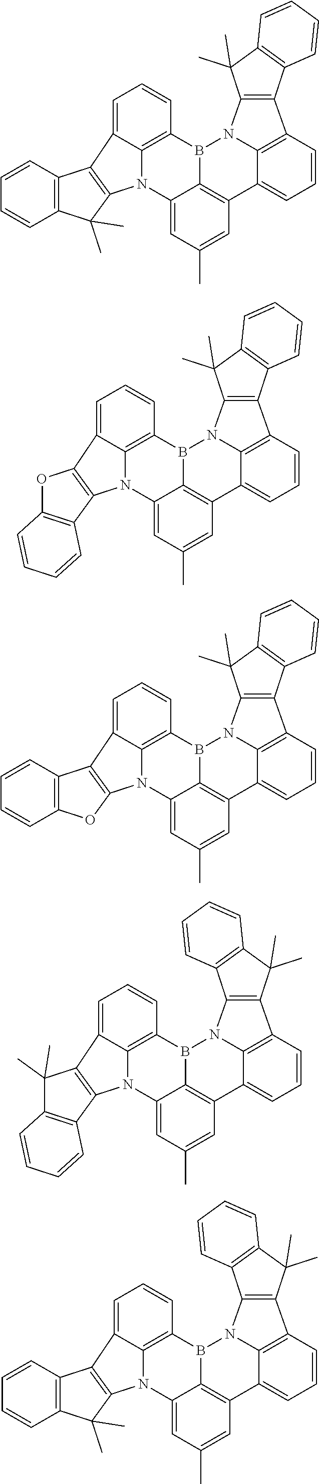 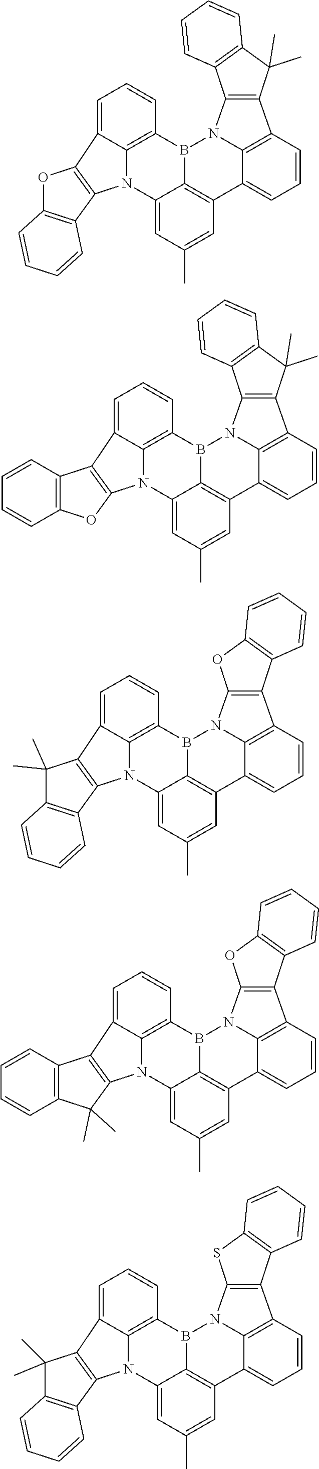 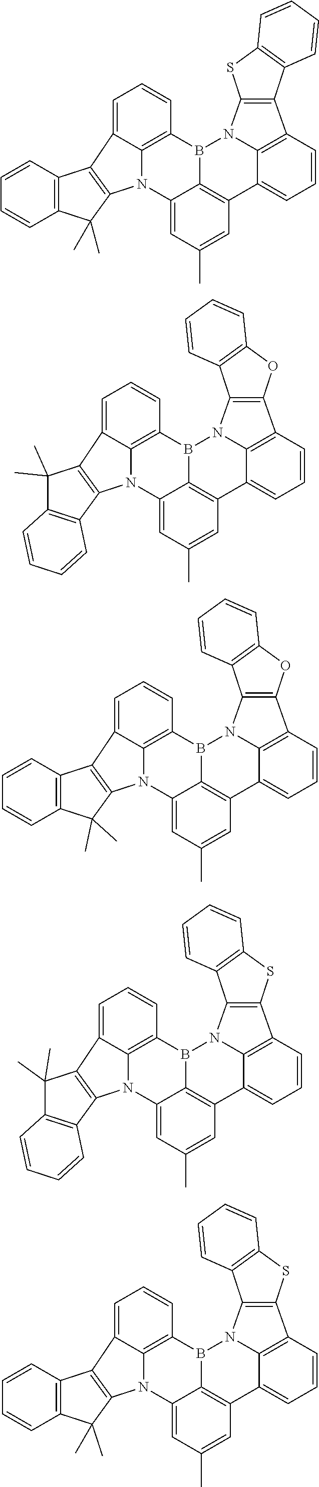 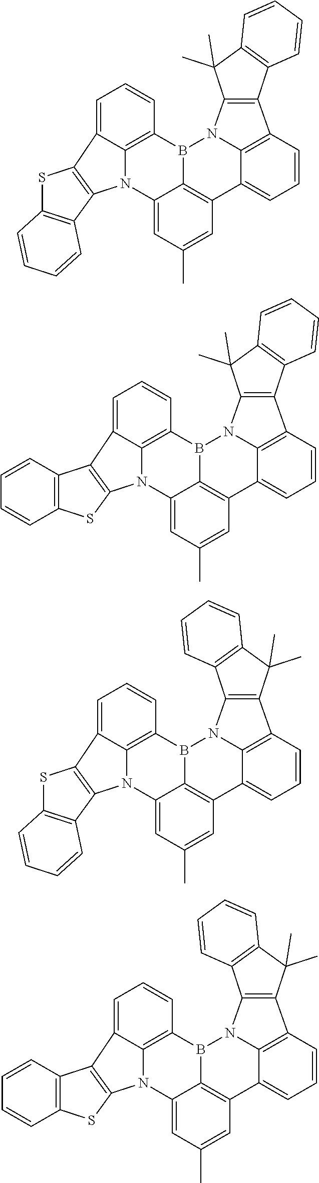 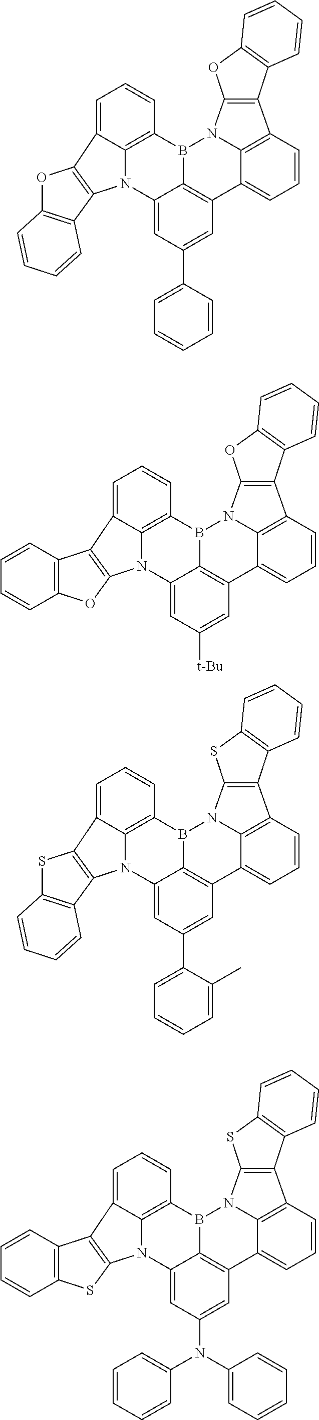 [SMILES: c1ccc(-c2cc3c4c(c2)-n2c5c(cccc5c5oc6ccccc6c52)B4n2c4oc5ccccc5c4c4cccc-3c42)cc1 ; CC(C)(C)c1cc2c3c(c1)-n1c4oc5ccccc5c4c4cccc(c41)B3n1c3oc4ccccc4c3c3cccc-2c31 ; Cc1ccccc1-c1cc2c3c(c1)-n1c4c(cccc4c4sc5ccccc5c41)B3n1c3sc4ccccc4c3c3cccc-2c31 ; c1ccc(N(c2ccccc2)c2cc3c4c(c2)-n2c5sc6ccccc6c5c5cccc(c52)B4n2c4sc5ccccc5c4c4cccc-3c42)cc1] 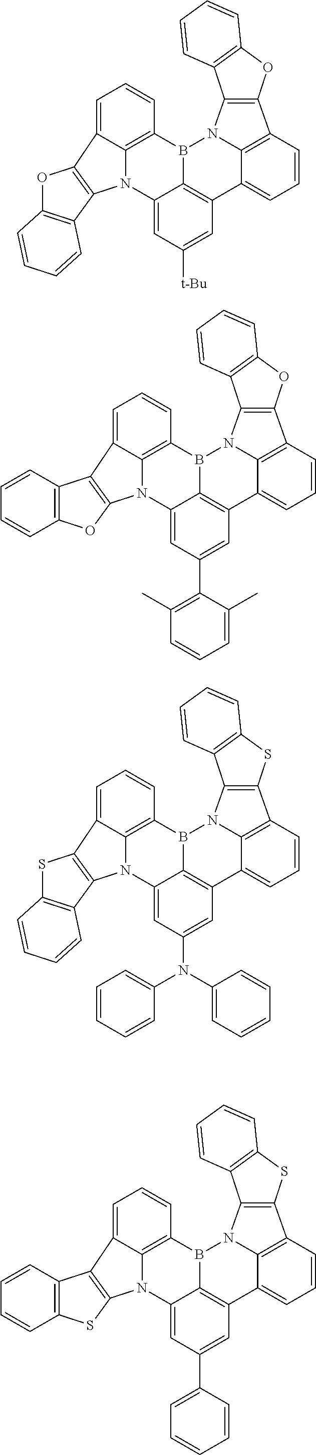 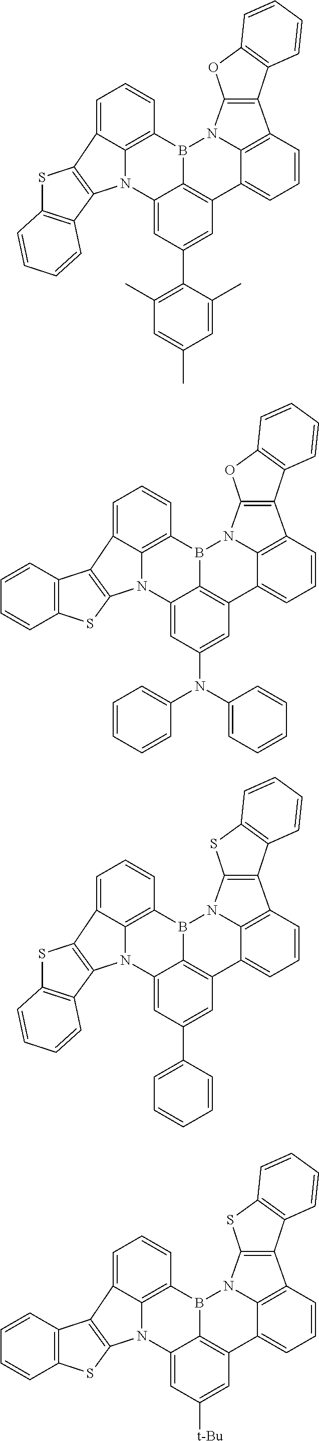 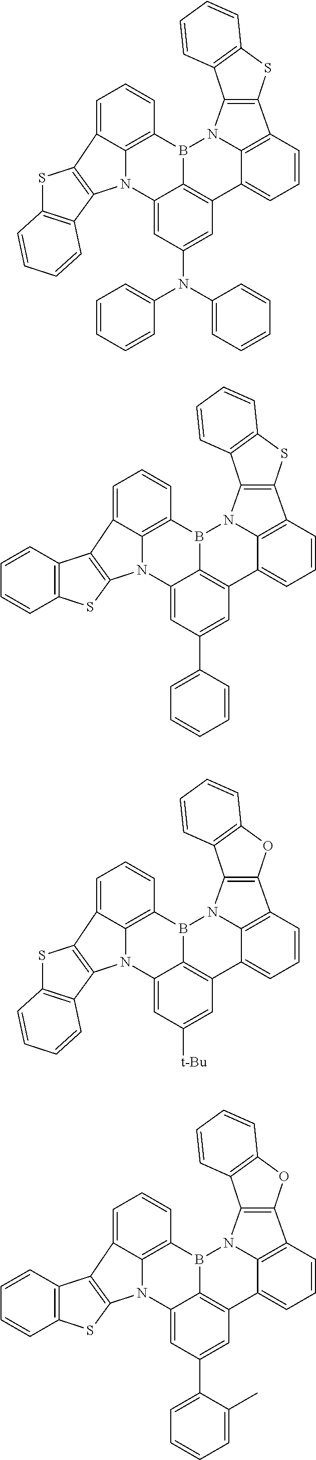 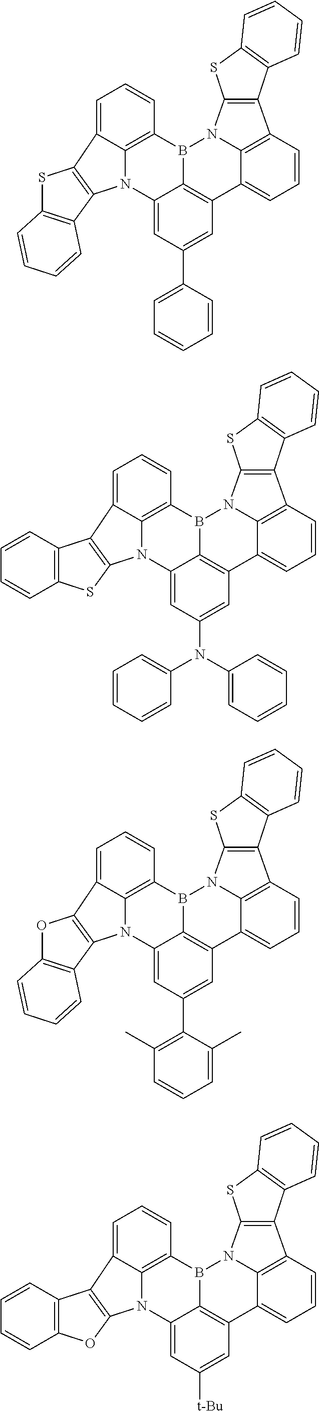 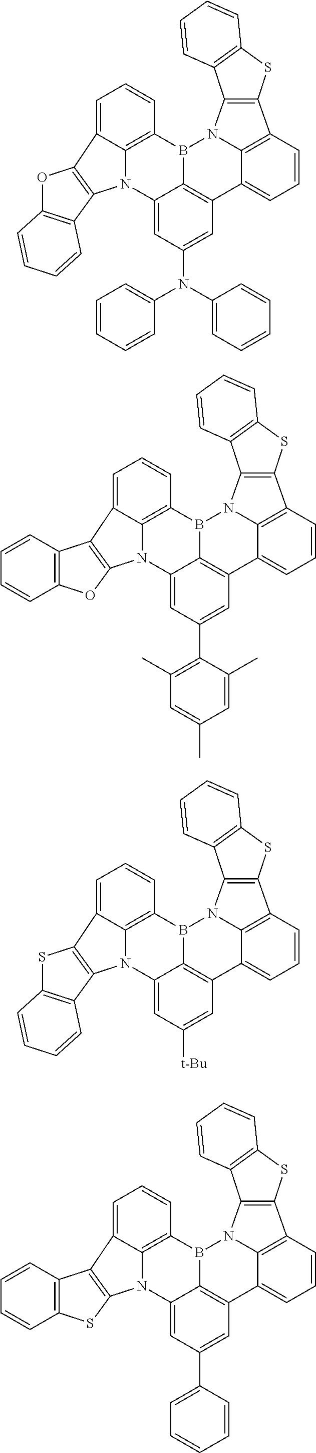 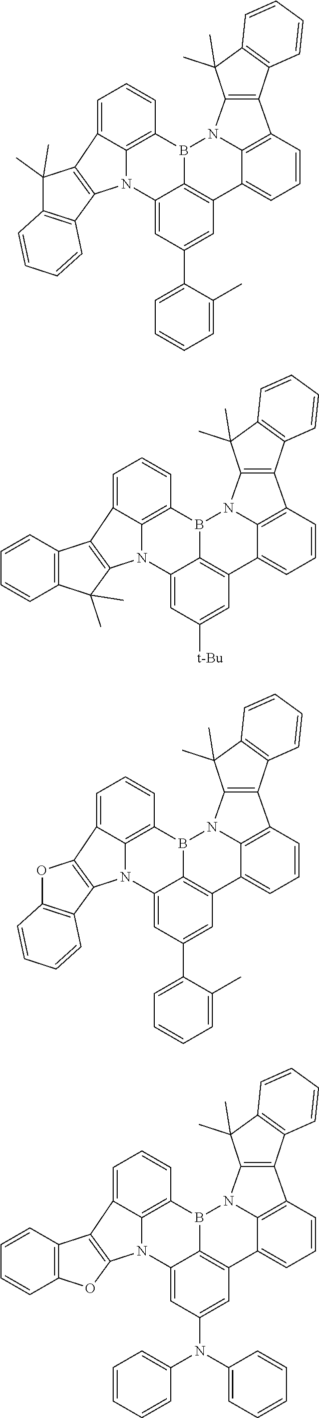 [SMILES: Cc1ccccc1-c1cc2c3c(c1)-n1c4c(c5cccc(c51)B3n1c3c(c5cccc-2c51)-c1ccccc1C3(C)C)C(C)(C)c1ccccc1-4 ; CC(C)(C)c1cc2c3c(c1)-n1c4c(c5cccc(c51)B3n1c3c(c5cccc-2c51)-c1ccccc1C3(C)C)-c1ccccc1C4(C)C ; Cc1ccccc1-c1cc2c3c(c1)-n1c4c(cccc4c4oc5ccccc5c41)B3n1c3c(c4cccc-2c41)-c1ccccc1C3(C)C ; CC1(C)c2ccccc2-c2c1n1c3c(cccc23)-c2cc(N(c3ccccc3)c3ccccc3)cc3c2B1c1cccc2c4c5ccccc5oc4n-3c12] 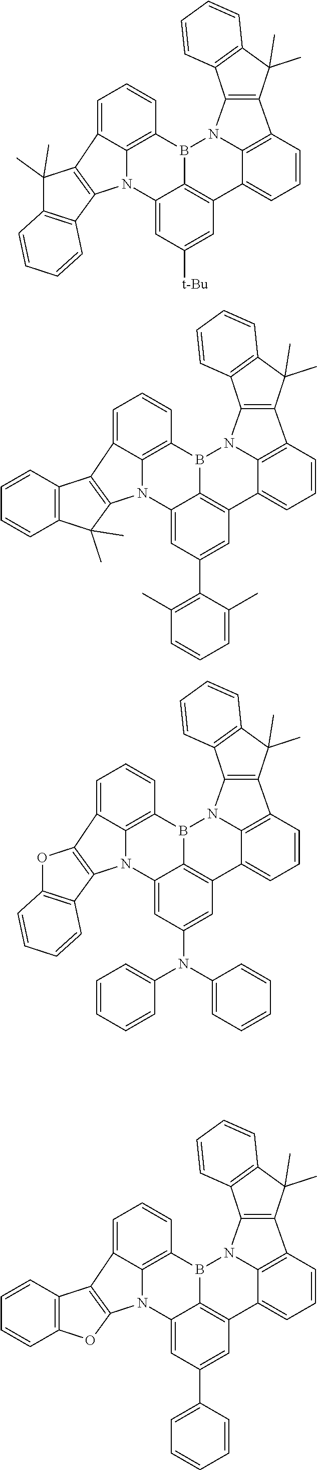 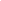 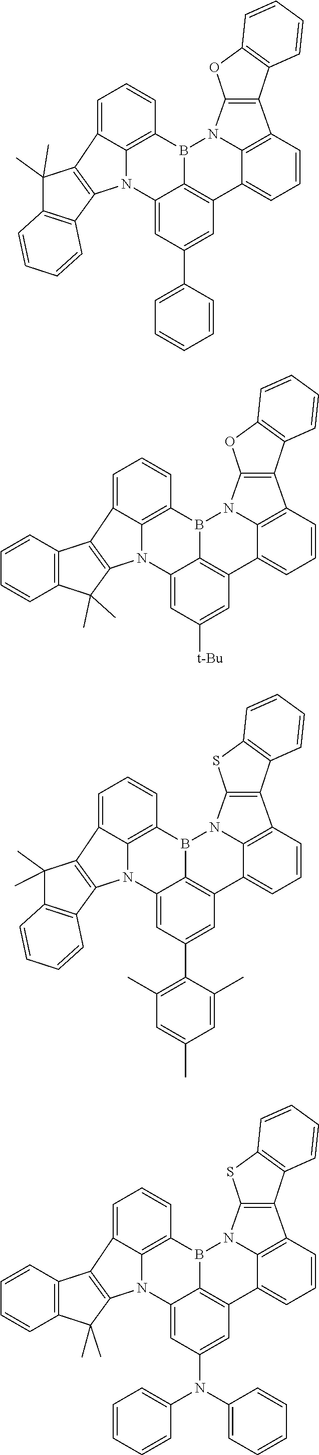 [SMILES: CC1(C)c2ccccc2-c2c1c1cccc3c1n2-c1cc(-c2ccccc2)cc2c1B3n1c3oc4ccccc4c3c3cccc-2c31 ; CC(C)(C)c1cc2c3c(c1)-n1c4c(c5cccc(c51)B3n1c3oc5ccccc5c3c3cccc-2c31)-c1ccccc1C4(C)C ; Cc1cc(C)c(-c2cc3c4c(c2)-n2c5c(c6cccc(c62)B4n2c4sc6ccccc6c4c4cccc-3c42)C(C)(C)c2ccccc2-5)c(C)c1 ; CC1(C)c2ccccc2-c2c1n1c3c(cccc23)B2c3c(cc(N(c4ccccc4)c4ccccc4)cc3-1)-c1cccc3c4c5ccccc5sc4n2c13] 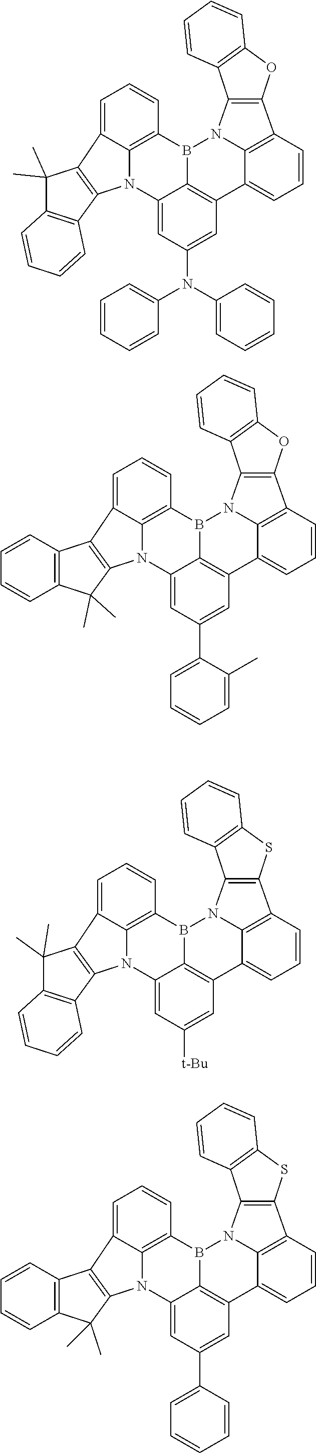 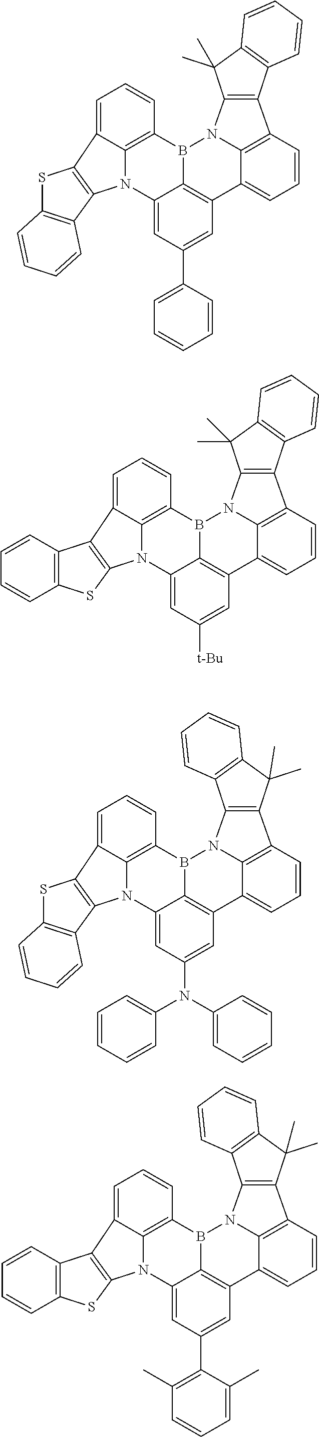 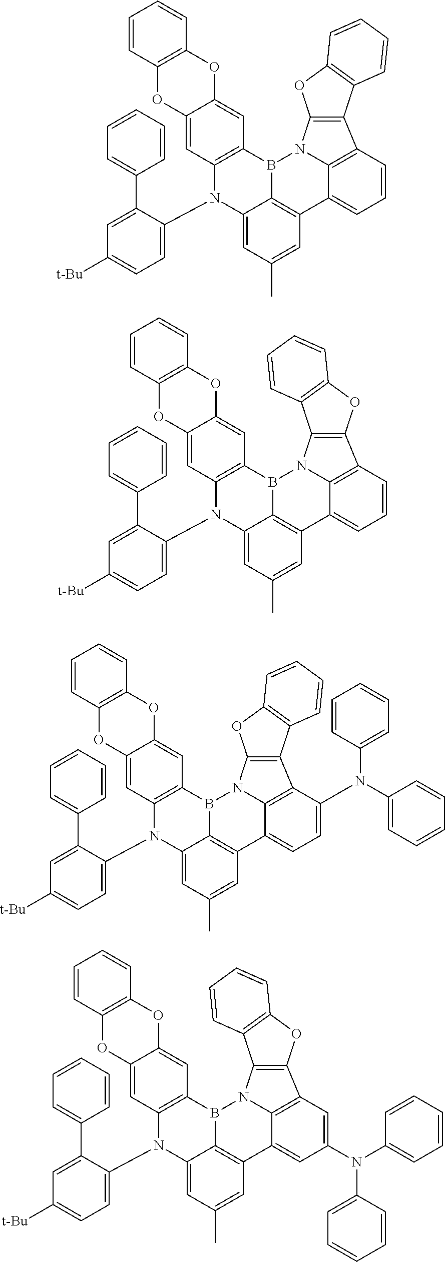 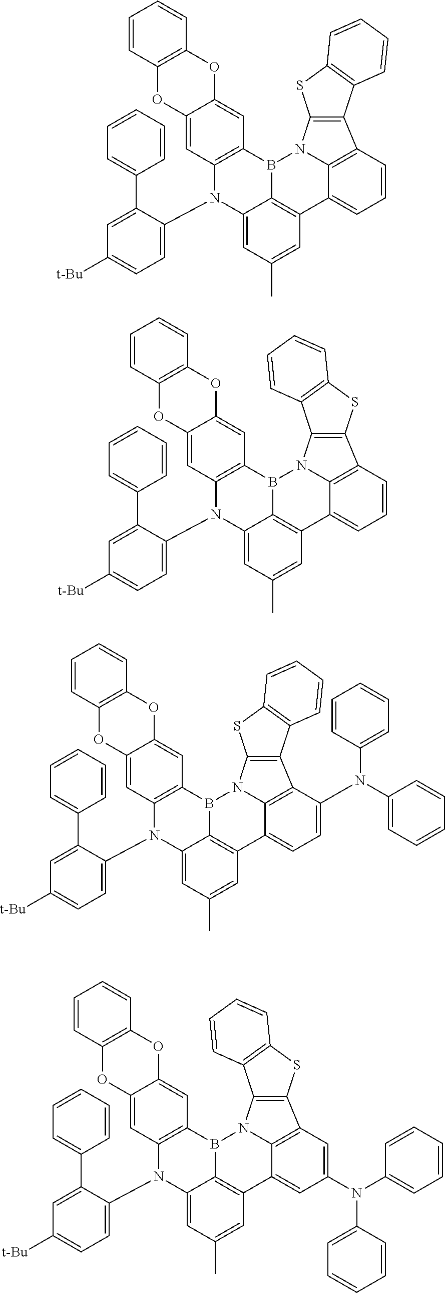 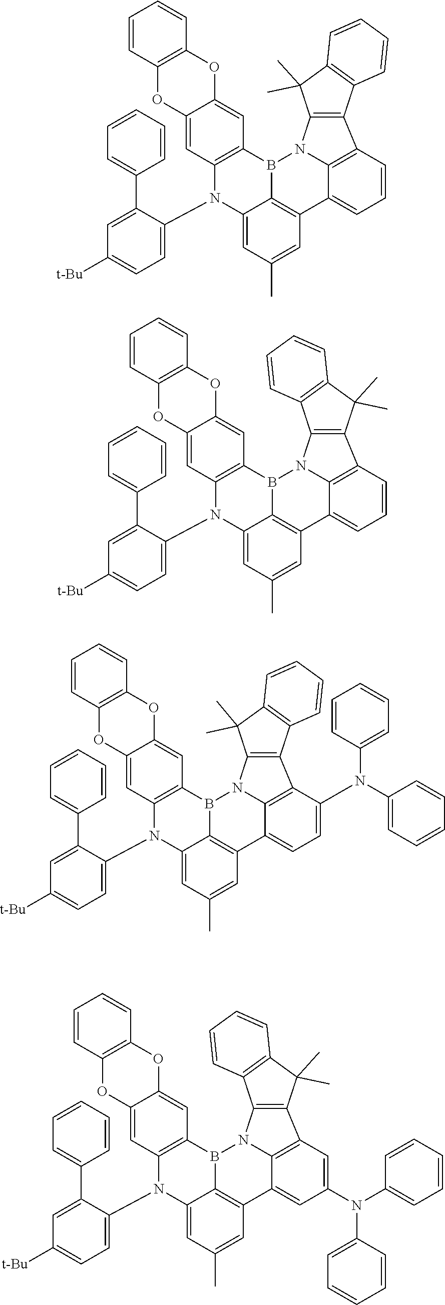 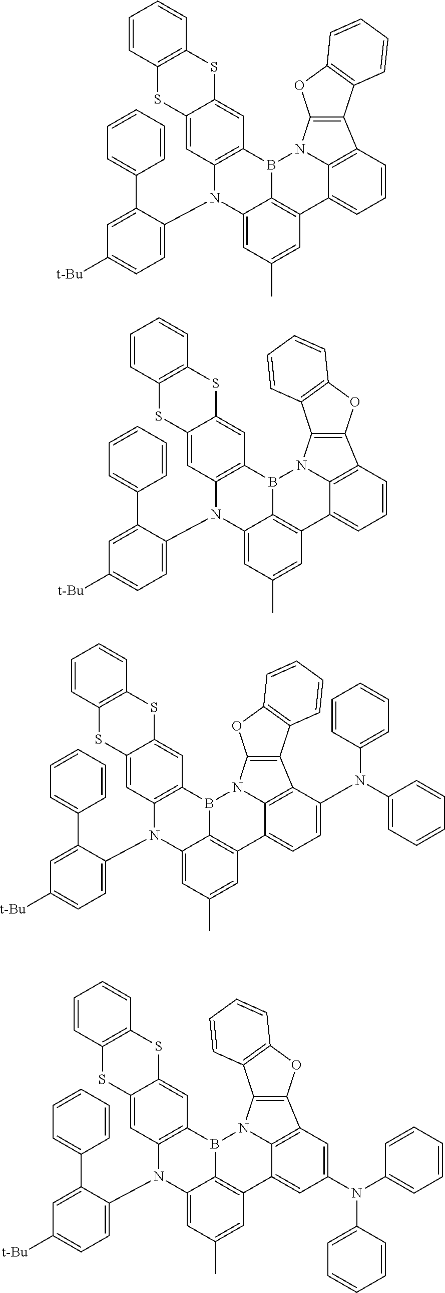 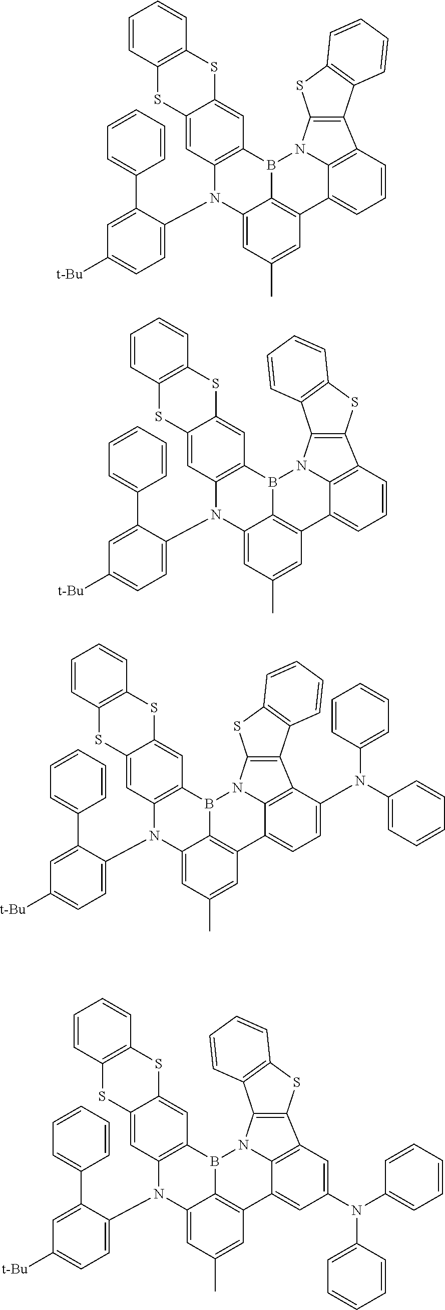 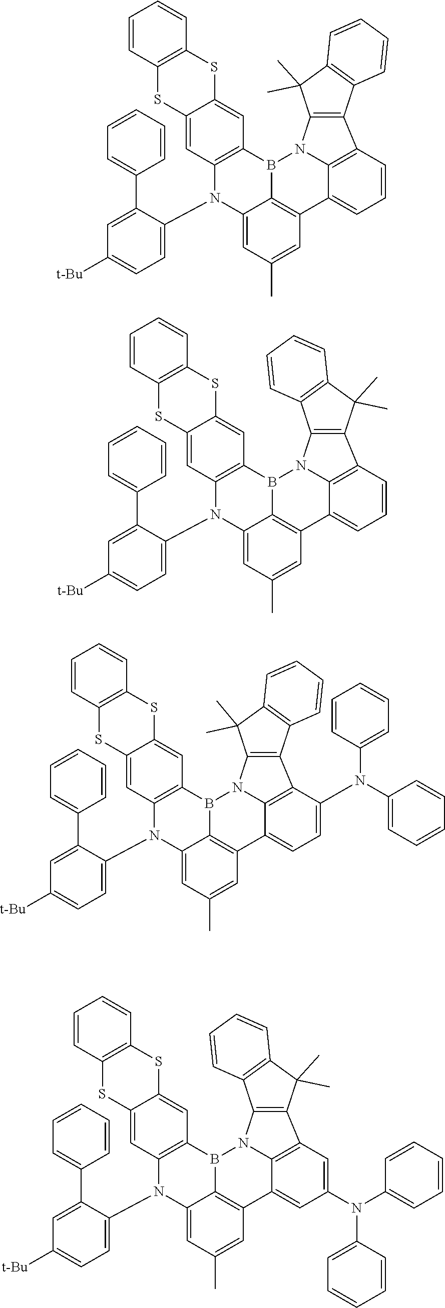 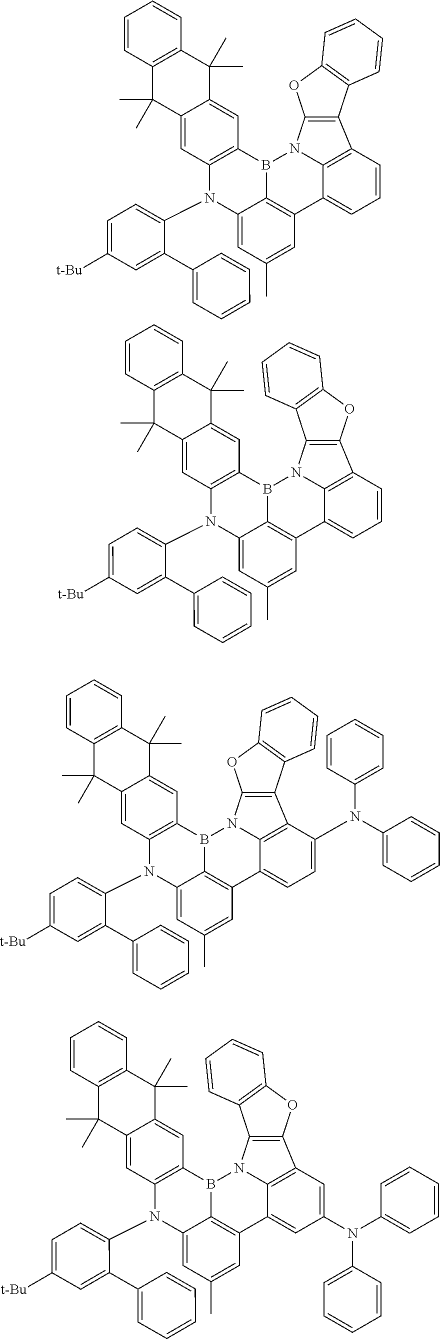 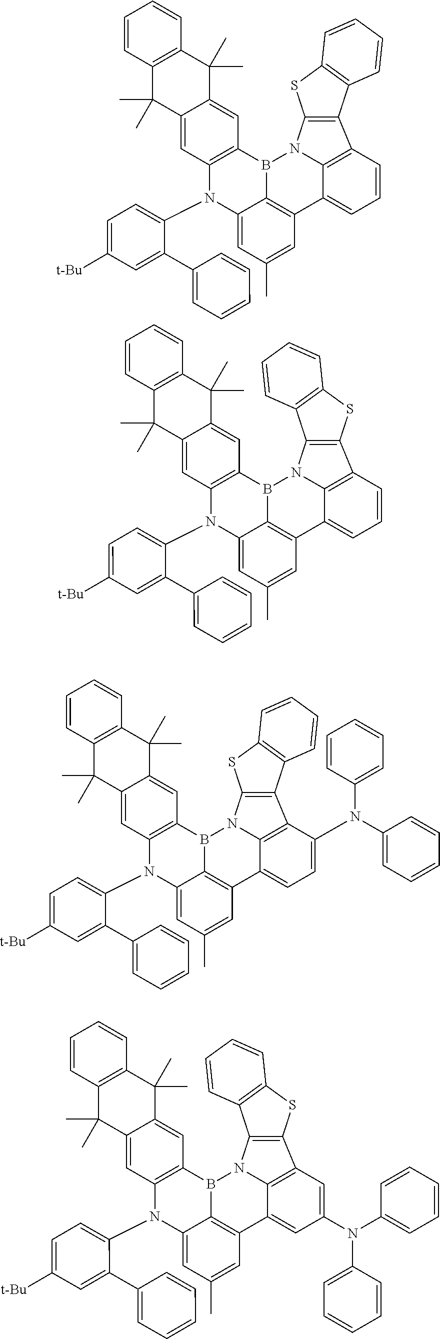 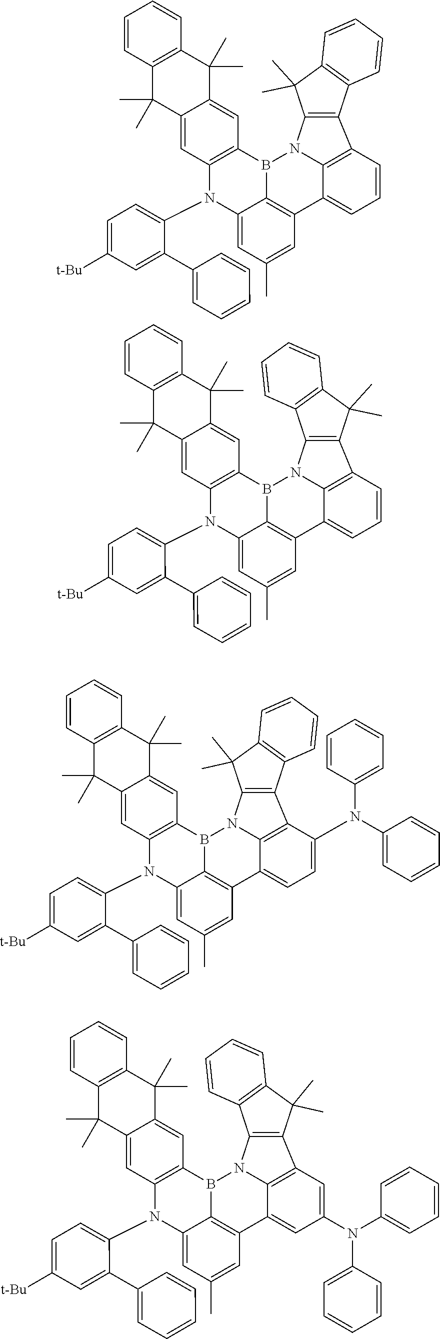 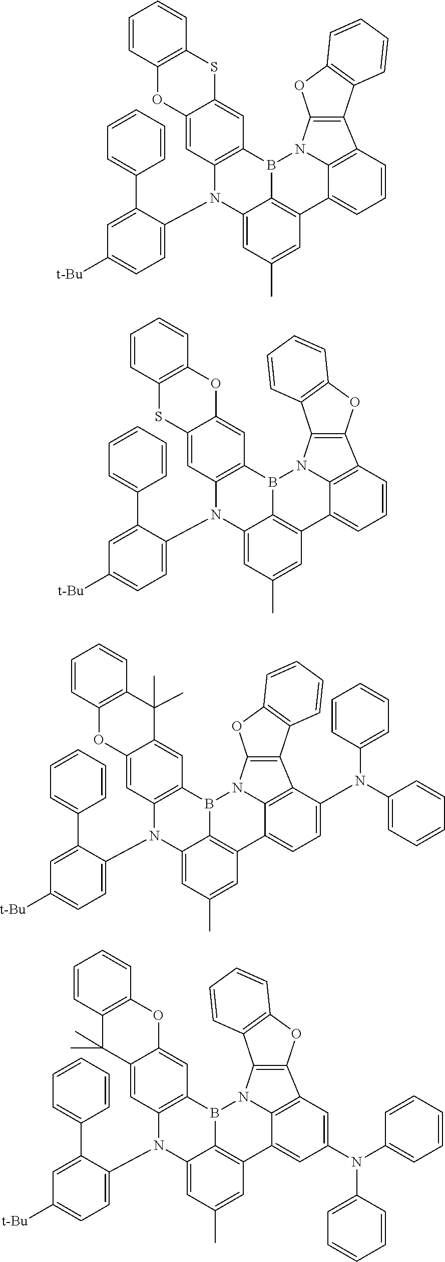 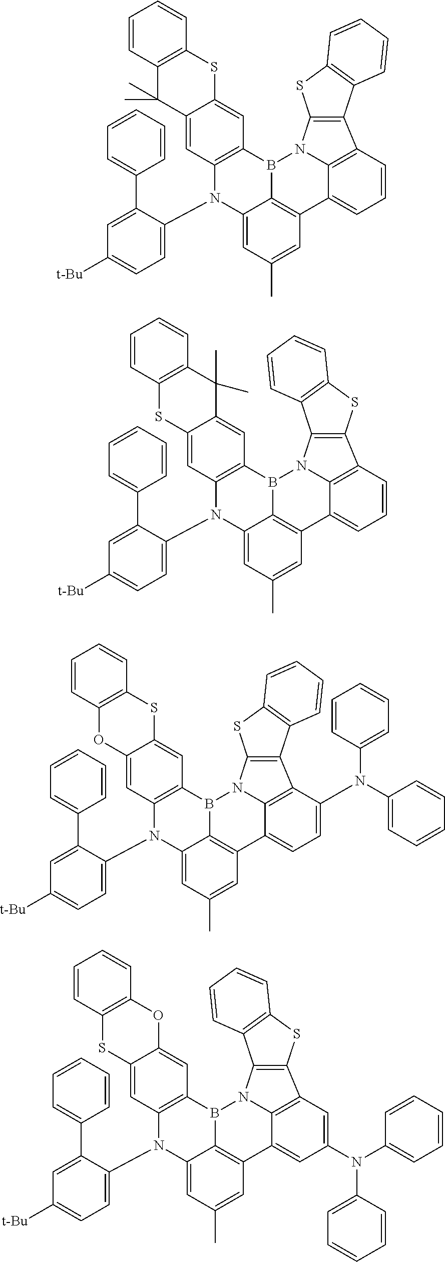 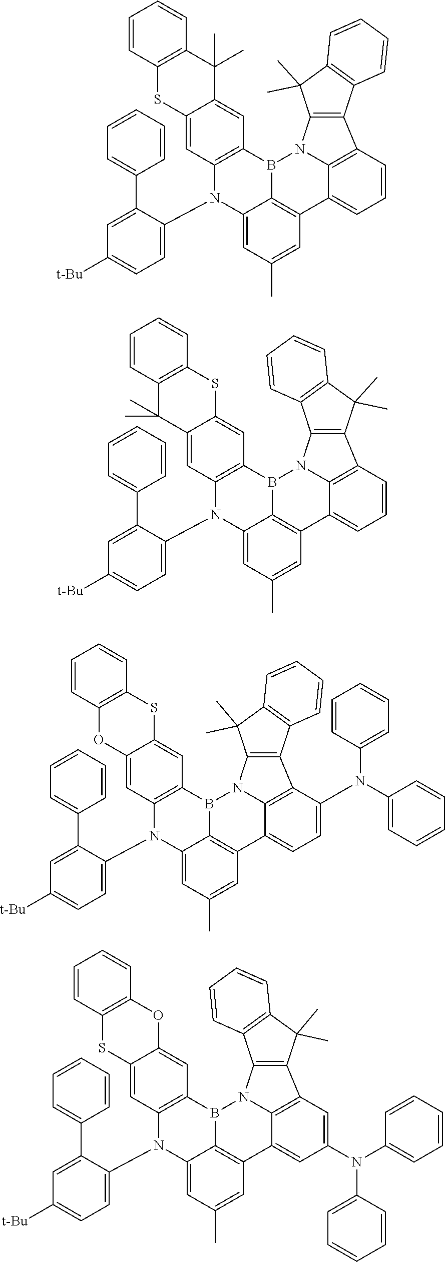 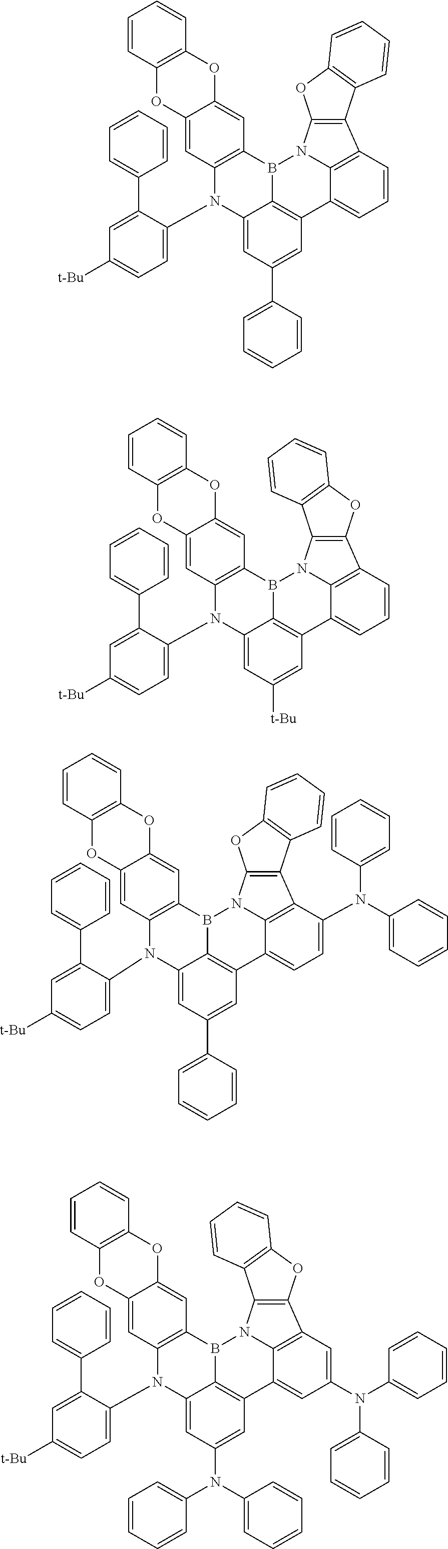 [SMILES: CC(C)(C)c1ccc(N2c3cc4c(cc3B3c5c(cc(-c6ccccc6)cc52)-c2cccc5c6c7ccccc7oc6n3c25)Oc2ccccc2O4)c(-c2ccccc2)c1 ; CC(C)(C)c1ccc(N2c3cc4c(cc3B3c5c(cc(C(C)(C)C)cc52)-c2cccc5c6oc7ccccc7c6n3c25)Oc2ccccc2O4)c(-c2ccccc2)c1 ; CC(C)(C)c1ccc(N2c3cc4c(cc3B3c5c(cc(-c6ccccc6)cc52)-c2ccc(N(c5ccccc5)c5ccccc5)c5c6c7ccccc7oc6n3c25)Oc2ccccc2O4)c(-c2ccccc2)c1 ; CC(C)(C)c1ccc(N2c3cc4c(cc3B3c5c(cc(N(c6ccccc6)c6ccccc6)cc52)-c2cc(N(c5ccccc5)c5ccccc5)cc5c6oc7ccccc7c6n3c25)Oc2ccccc2O4)c(-c2ccccc2)c1] 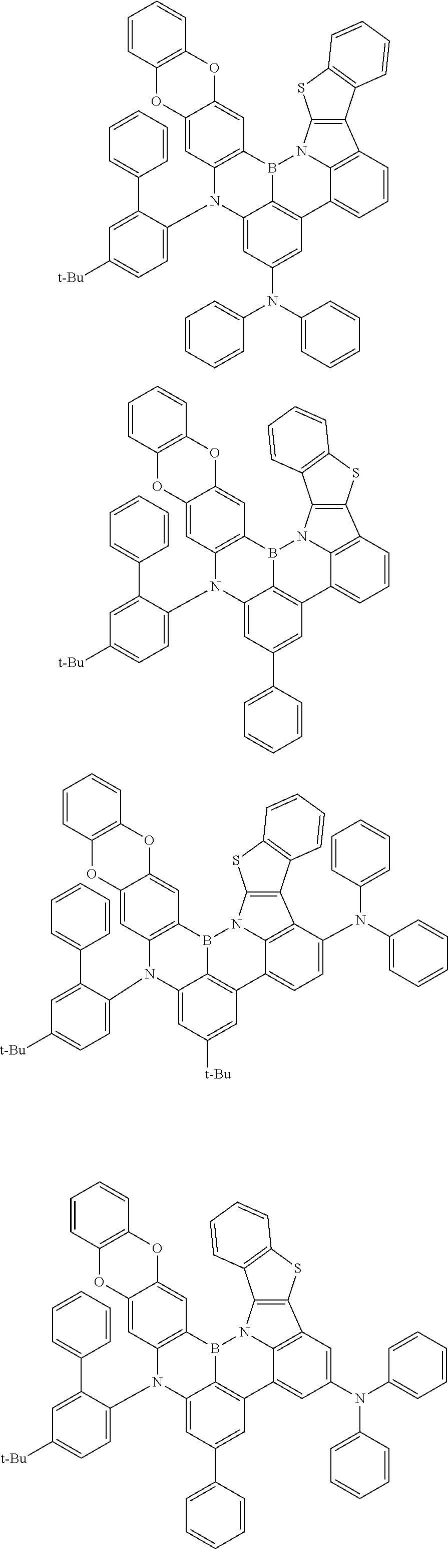 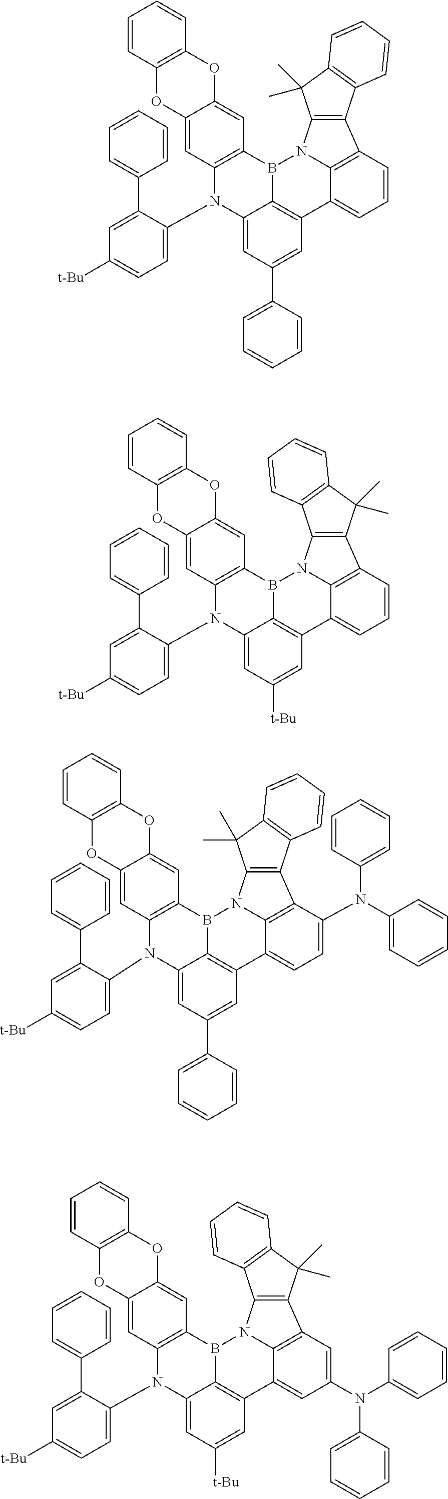 [SMILES: CC(C)(C)c1ccc(N2c3cc4c(cc3B3c5c(cc(-c6ccccc6)cc52)-c2cccc5c6c(n3c25)C(C)(C)c2ccccc2-6)Oc2ccccc2O4)c(-c2ccccc2)c1 ; CC(C)(C)c1ccc(N2c3cc4c(cc3B3c5c(cc(C(C)(C)C)cc52)-c2cccc5c6c(n3c25)-c2ccccc2C6(C)C)Oc2ccccc2O4)c(-c2ccccc2)c1 ; CC(C)(C)c1ccc(N2c3cc4c(cc3B3c5c(cc(-c6ccccc6)cc52)-c2ccc(N(c5ccccc5)c5ccccc5)c5c6c(n3c25)C(C)(C)c2ccccc2-6)Oc2ccccc2O4)c(-c2ccccc2)c1 ; CC(C)(C)c1ccc(N2c3cc4c(cc3B3c5c(cc(C(C)(C)C)cc52)-c2cc(N(c5ccccc5)c5ccccc5)cc5c6c(n3c25)-c2ccccc2C6(C)C)Oc2ccccc2O4)c(-c2ccccc2)c1] 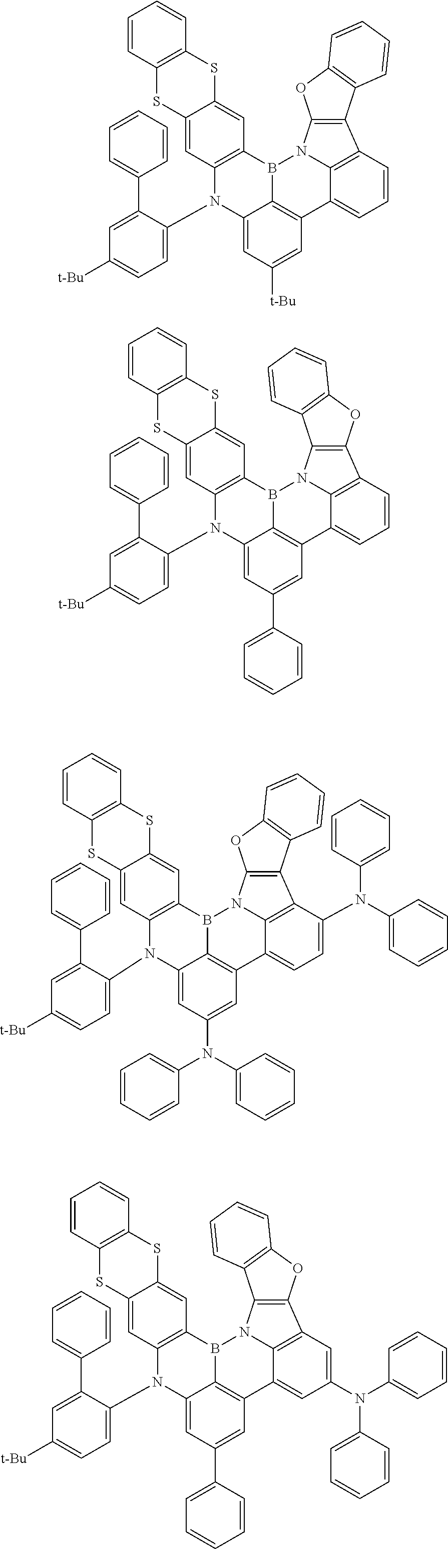 [SMILES: CC(C)(C)c1ccc(N2c3cc4c(cc3B3c5c(cc(C(C)(C)C)cc52)-c2cccc5c6c7ccccc7oc6n3c25)Sc2ccccc2S4)c(-c2ccccc2)c1 ; CC(C)(C)c1ccc(N2c3cc4c(cc3B3c5c(cc(-c6ccccc6)cc52)-c2cccc5c6oc7ccccc7c6n3c25)Sc2ccccc2S4)c(-c2ccccc2)c1 ; CC(C)(C)c1ccc(N2c3cc4c(cc3B3c5c(cc(N(c6ccccc6)c6ccccc6)cc52)-c2ccc(N(c5ccccc5)c5ccccc5)c5c6c7ccccc7oc6n3c25)Sc2ccccc2S4)c(-c2ccccc2)c1 ; CC(C)(C)c1ccc(N2c3cc4c(cc3B3c5c(cc(-c6ccccc6)cc52)-c2cc(N(c5ccccc5)c5ccccc5)cc5c6oc7ccccc7c6n3c25)Sc2ccccc2S4)c(-c2ccccc2)c1] 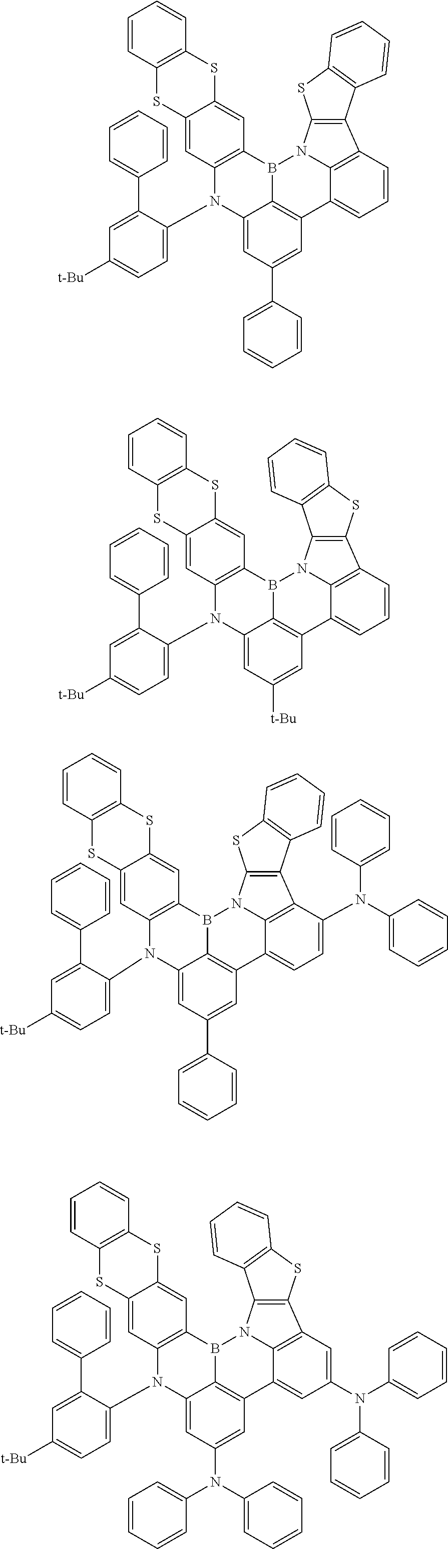 [SMILES: CC(C)(C)c1ccc(N2c3cc4c(cc3B3c5c(cc(-c6ccccc6)cc52)-c2cccc5c6c7ccccc7sc6n3c25)Sc2ccccc2S4)c(-c2ccccc2)c1 ; CC(C)(C)c1ccc(N2c3cc4c(cc3B3c5c(cc(C(C)(C)C)cc52)-c2cccc5c6sc7ccccc7c6n3c25)Sc2ccccc2S4)c(-c2ccccc2)c1 ; CC(C)(C)c1ccc(N2c3cc4c(cc3B3c5c(cc(-c6ccccc6)cc52)-c2ccc(N(c5ccccc5)c5ccccc5)c5c6c7ccccc7sc6n3c25)Sc2ccccc2S4)c(-c2ccccc2)c1 ; CC(C)(C)c1ccc(N2c3cc4c(cc3B3c5c(cc(N(c6ccccc6)c6ccccc6)cc52)-c2cc(N(c5ccccc5)c5ccccc5)cc5c6sc7ccccc7c6n3c25)Sc2ccccc2S4)c(-c2ccccc2)c1] 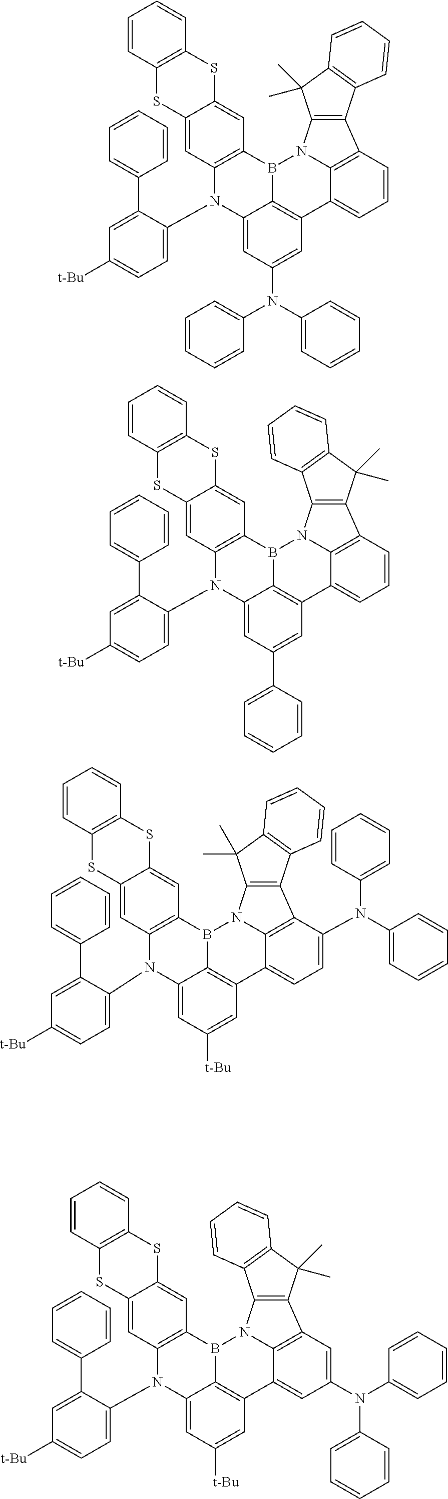 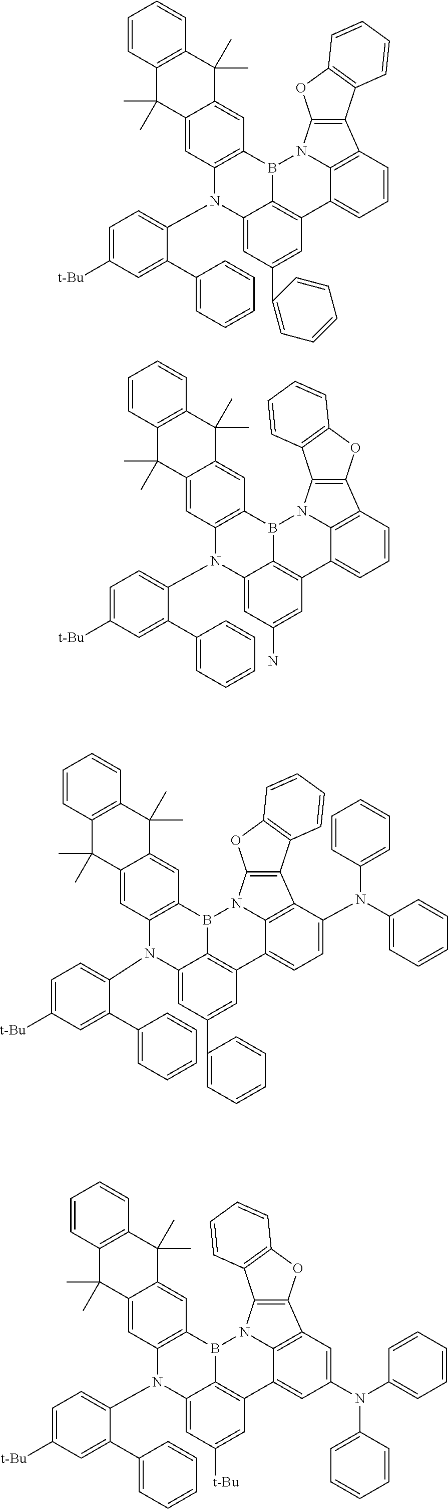 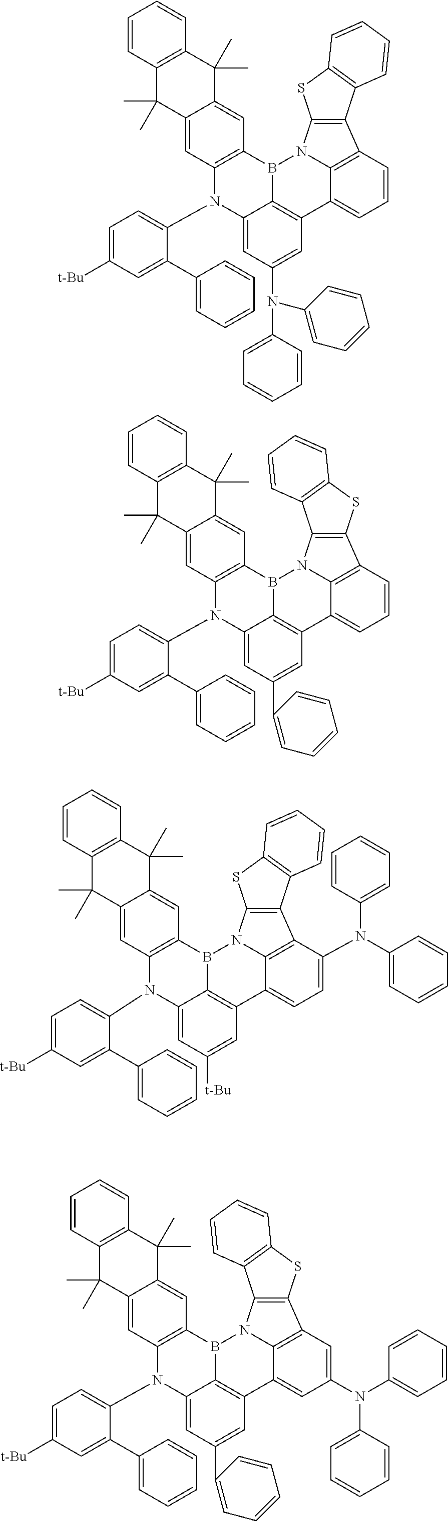 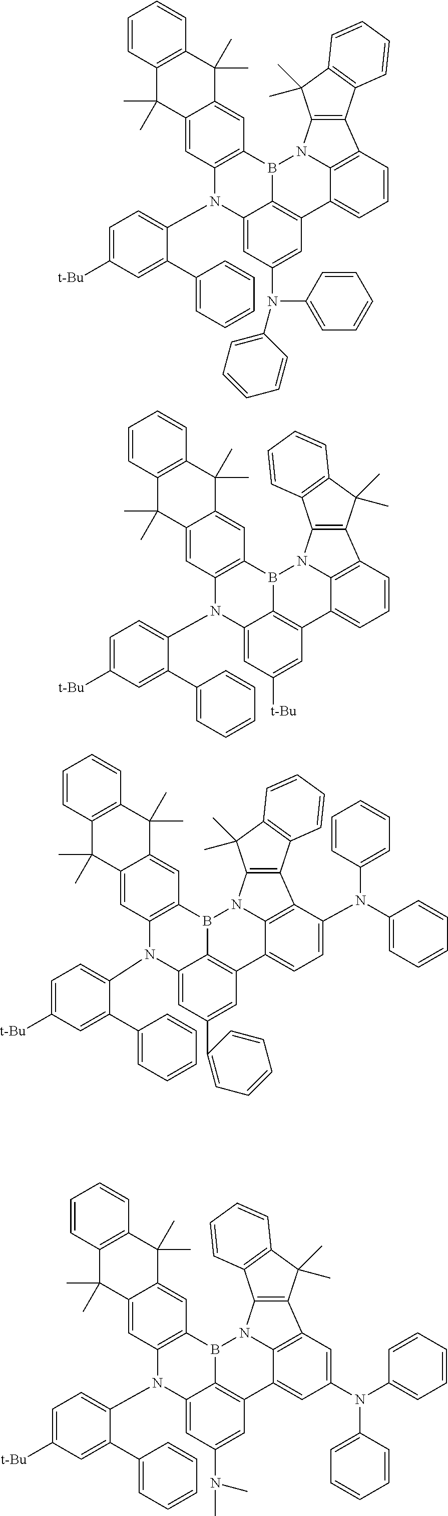 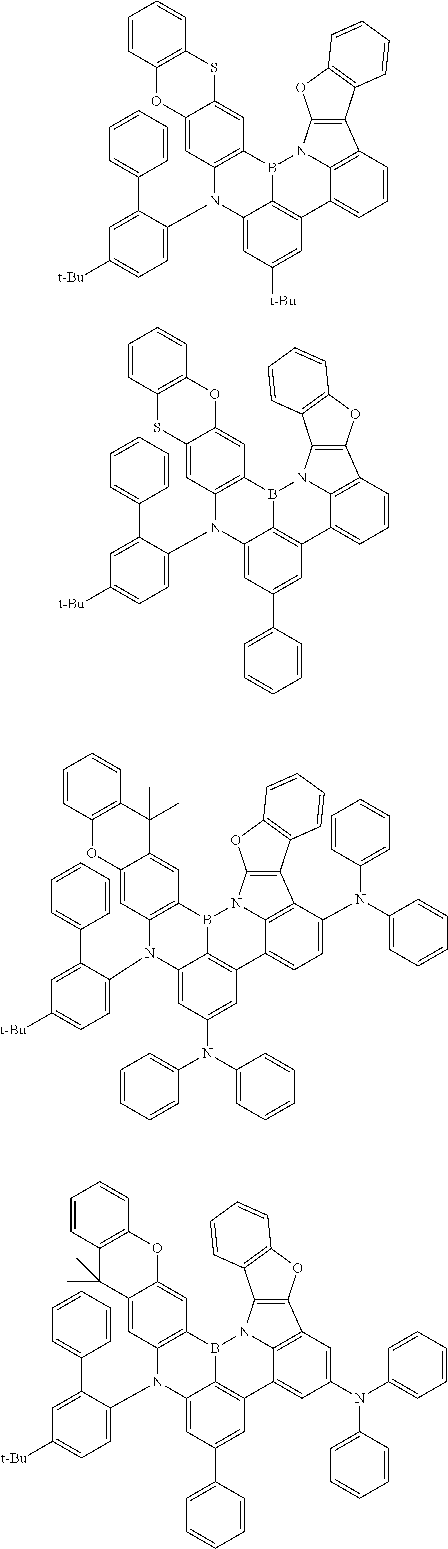 [SMILES: CC(C)(C)c1ccc(N2c3cc4c(cc3B3c5c(cc(C(C)(C)C)cc52)-c2cccc5c6c7ccccc7oc6n3c25)Sc2ccccc2O4)c(-c2ccccc2)c1 ; CC(C)(C)c1ccc(N2c3cc4c(cc3B3c5c(cc(-c6ccccc6)cc52)-c2cccc5c6oc7ccccc7c6n3c25)Oc2ccccc2S4)c(-c2ccccc2)c1 ; CC(C)(C)c1ccc(N2c3cc4c(cc3B3c5c(cc(N(c6ccccc6)c6ccccc6)cc52)-c2ccc(N(c5ccccc5)c5ccccc5)c5c6c7ccccc7oc6n3c25)C(C)(C)c2ccccc2O4)c(-c2ccccc2)c1 ; CC(C)(C)c1ccc(N2c3cc4c(cc3B3c5c(cc(-c6ccccc6)cc52)-c2cc(N(c5ccccc5)c5ccccc5)cc5c6oc7ccccc7c6n3c25)Oc2ccccc2C4(C)C)c(-c2ccccc2)c1] 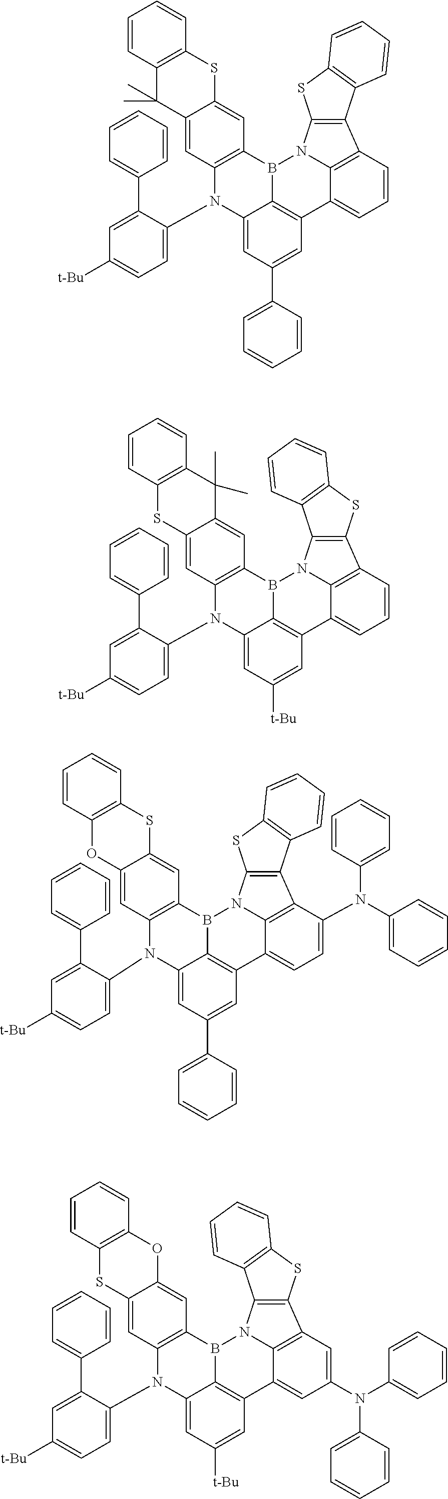 [SMILES: CC(C)(C)c1ccc(N2c3cc4c(cc3B3c5c(cc(-c6ccccc6)cc52)-c2cccc5c6c7ccccc7sc6n3c25)Sc2ccccc2C4(C)C)c(-c2ccccc2)c1 ; CC(C)(C)c1ccc(N2c3cc4c(cc3B3c5c(cc(C(C)(C)C)cc52)-c2cccc5c6sc7ccccc7c6n3c25)C(C)(C)c2ccccc2S4)c(-c2ccccc2)c1 ; CC(C)(C)c1ccc(N2c3cc4c(cc3B3c5c(cc(-c6ccccc6)cc52)-c2ccc(N(c5ccccc5)c5ccccc5)c5c6c7ccccc7sc6n3c25)Sc2ccccc2O4)c(-c2ccccc2)c1 ; CC(C)(C)c1ccc(N2c3cc4c(cc3B3c5c(cc(C(C)(C)C)cc52)-c2cc(N(c5ccccc5)c5ccccc5)cc5c6sc7ccccc7c6n3c25)Oc2ccccc2S4)c(-c2ccccc2)c1] 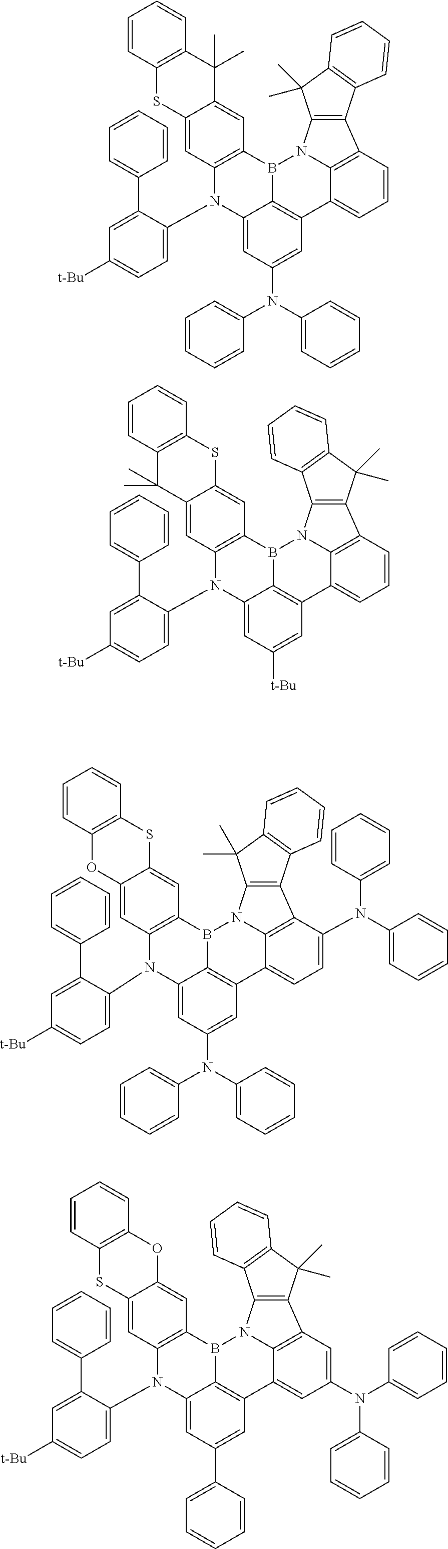 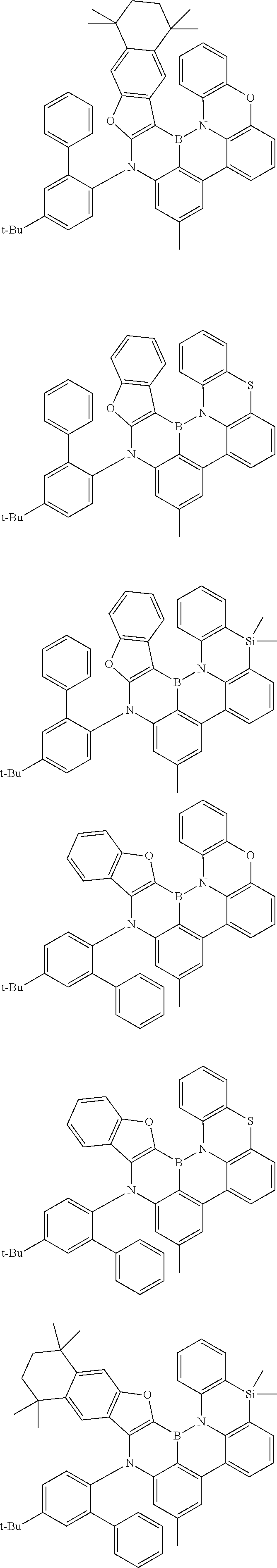 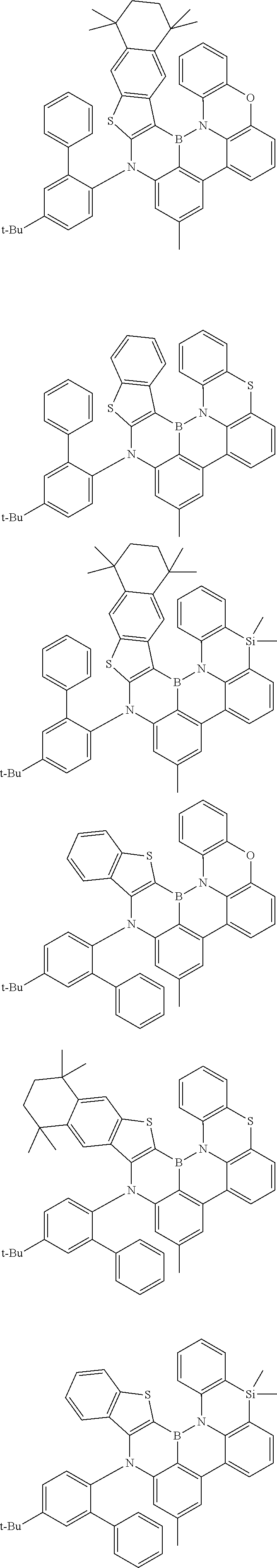 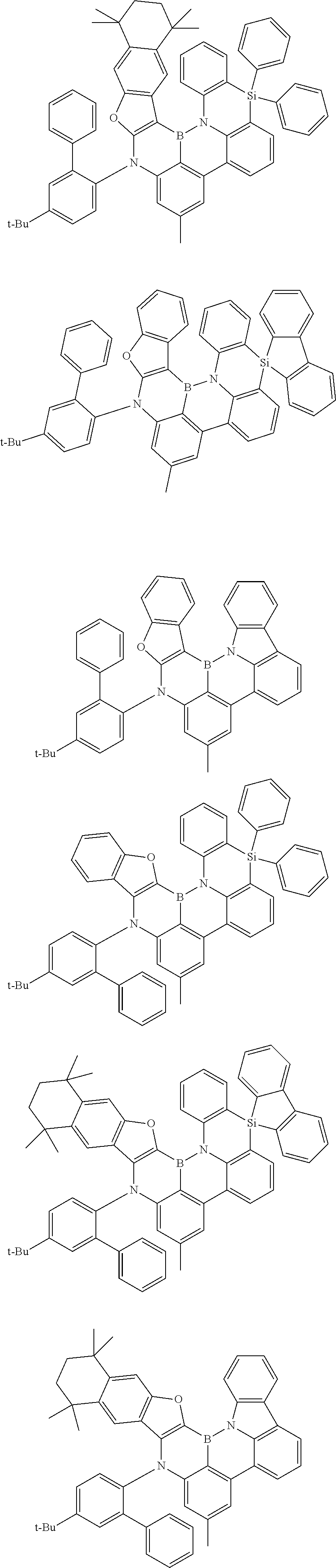 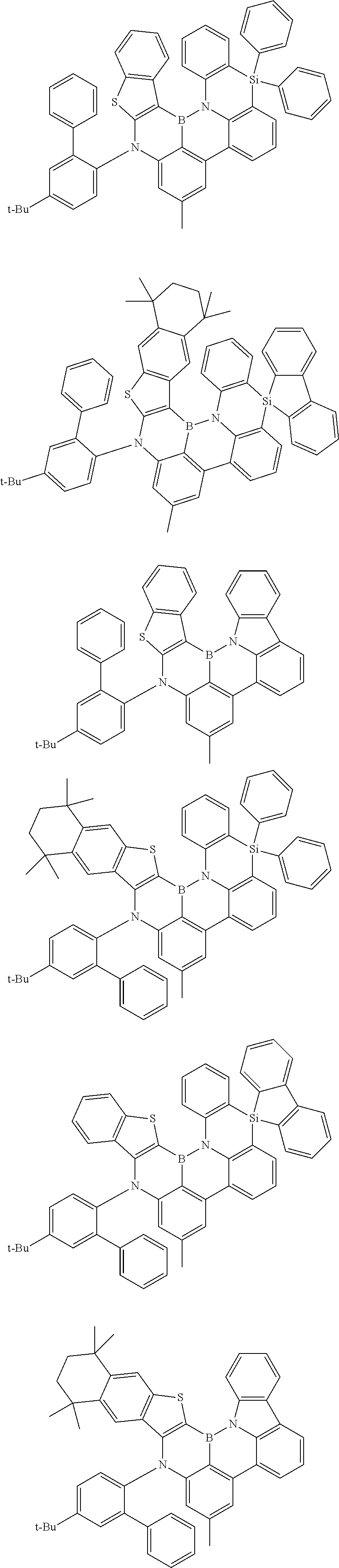 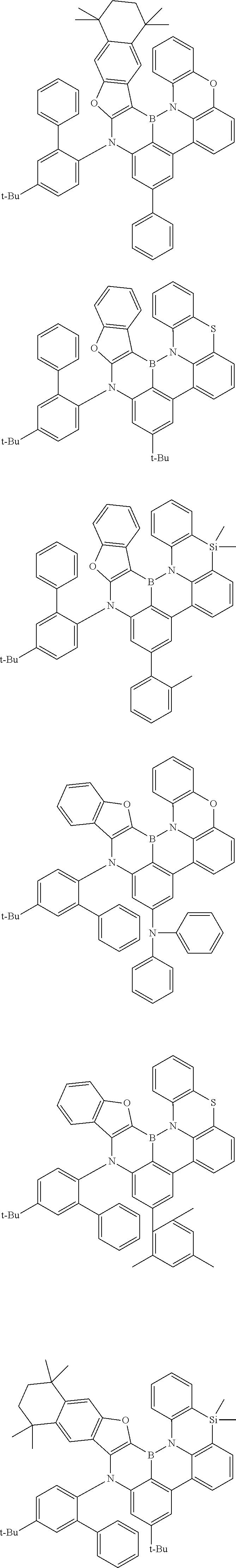 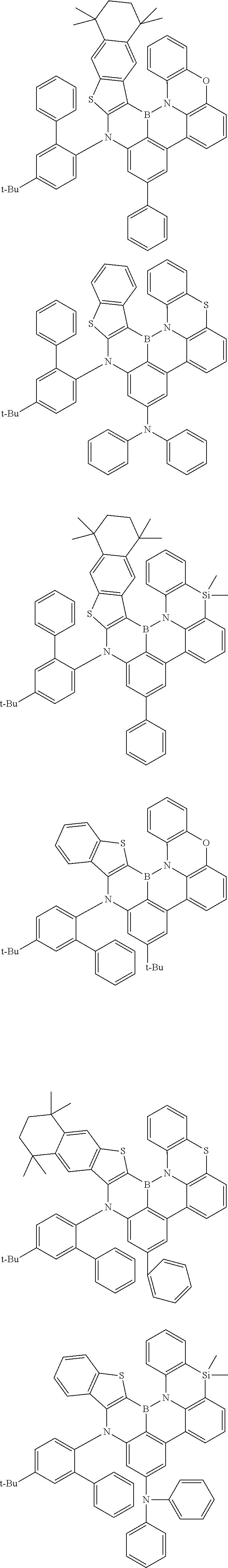 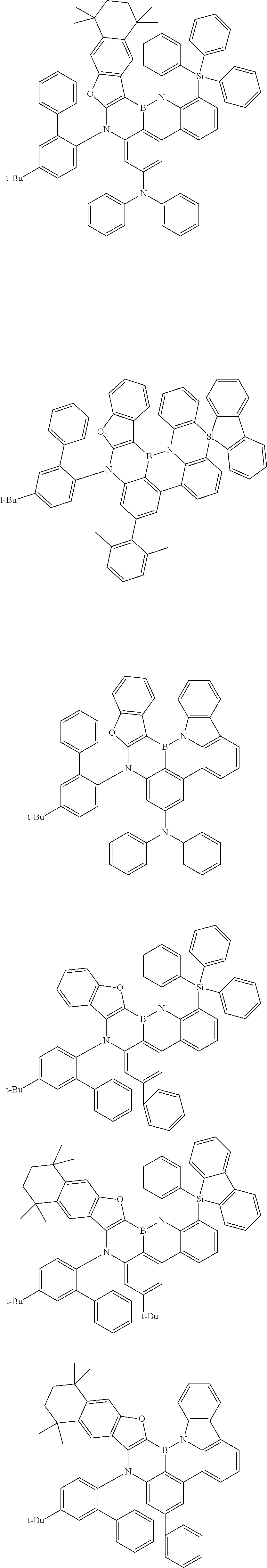 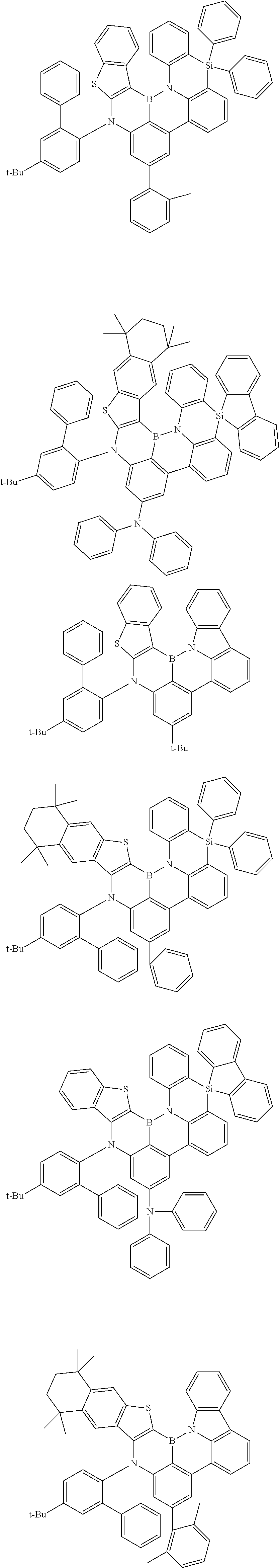 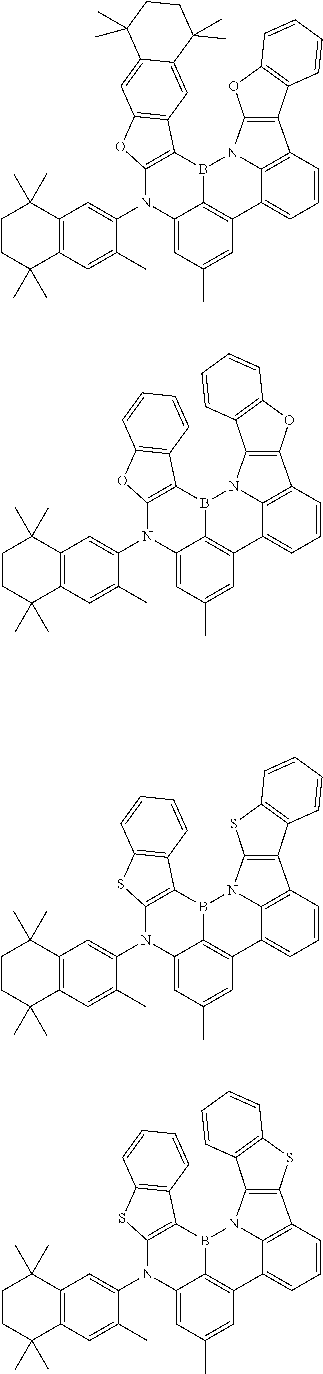 [SMILES: Cc1cc2c3c(c1)N(c1cc4c(cc1C)C(C)(C)CCC4(C)C)c1oc4cc5c(cc4c1B3n1c3oc4ccccc4c3c3cccc-2c31)C(C)(C)CCC5(C)C ; Cc1cc2c3c(c1)N(c1cc4c(cc1C)C(C)(C)CCC4(C)C)c1oc4ccccc4c1B3n1c3c-2cccc3c2oc3ccccc3c21 ; Cc1cc2c3c(c1)N(c1cc4c(cc1C)C(C)(C)CCC4(C)C)c1sc4ccccc4c1B3n1c3sc4ccccc4c3c3cccc-2c31 ; Cc1cc2c3c(c1)N(c1cc4c(cc1C)C(C)(C)CCC4(C)C)c1sc4ccccc4c1B3n1c3c-2cccc3c2sc3ccccc3c21] 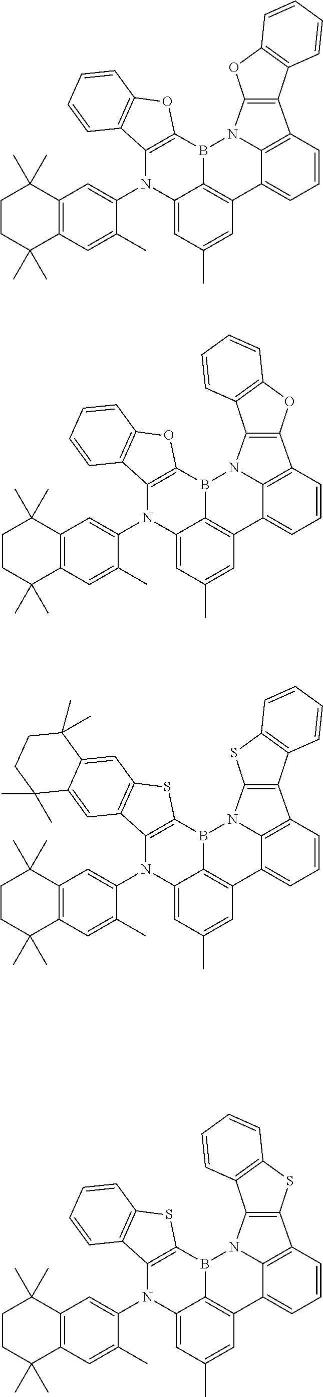 [SMILES: Cc1cc2c3c(c1)N(c1cc4c(cc1C)C(C)(C)CCC4(C)C)c1c(oc4ccccc14)B3n1c3oc4ccccc4c3c3cccc-2c31 ; Cc1cc2c3c(c1)N(c1cc4c(cc1C)C(C)(C)CCC4(C)C)c1c(oc4ccccc14)B3n1c3c-2cccc3c2oc3ccccc3c21 ; Cc1cc2c3c(c1)N(c1cc4c(cc1C)C(C)(C)CCC4(C)C)c1c(sc4cc5c(cc14)C(C)(C)CCC5(C)C)B3n1c3sc4ccccc4c3c3cccc-2c31 ; Cc1cc2c3c(c1)N(c1cc4c(cc1C)C(C)(C)CCC4(C)C)c1c(sc4ccccc14)B3n1c3c-2cccc3c2sc3ccccc3c21] 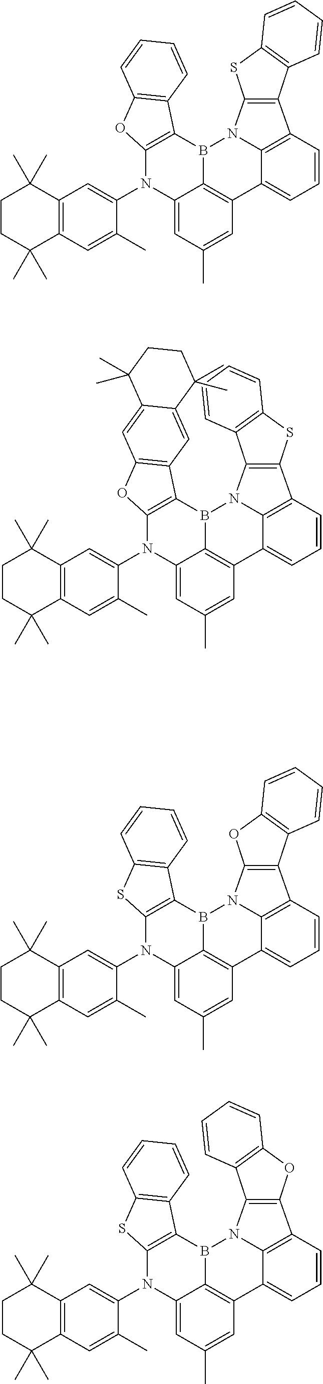 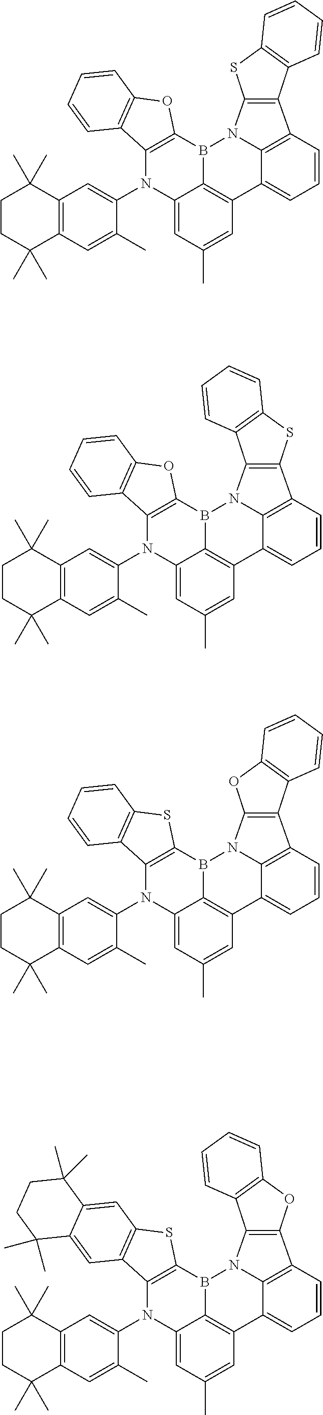 [SMILES: Cc1cc2c3c(c1)N(c1cc4c(cc1C)C(C)(C)CCC4(C)C)c1c(oc4ccccc14)B3n1c3sc4ccccc4c3c3cccc-2c31 ; Cc1cc2c3c(c1)N(c1cc4c(cc1C)C(C)(C)CCC4(C)C)c1c(oc4ccccc14)B3n1c3c-2cccc3c2sc3ccccc3c21 ; Cc1cc2c3c(c1)N(c1cc4c(cc1C)C(C)(C)CCC4(C)C)c1c(sc4ccccc14)B3n1c3oc4ccccc4c3c3cccc-2c31 ; Cc1cc2c3c(c1)N(c1cc4c(cc1C)C(C)(C)CCC4(C)C)c1c(sc4cc5c(cc14)C(C)(C)CCC5(C)C)B3n1c3c-2cccc3c2oc3ccccc3c21] 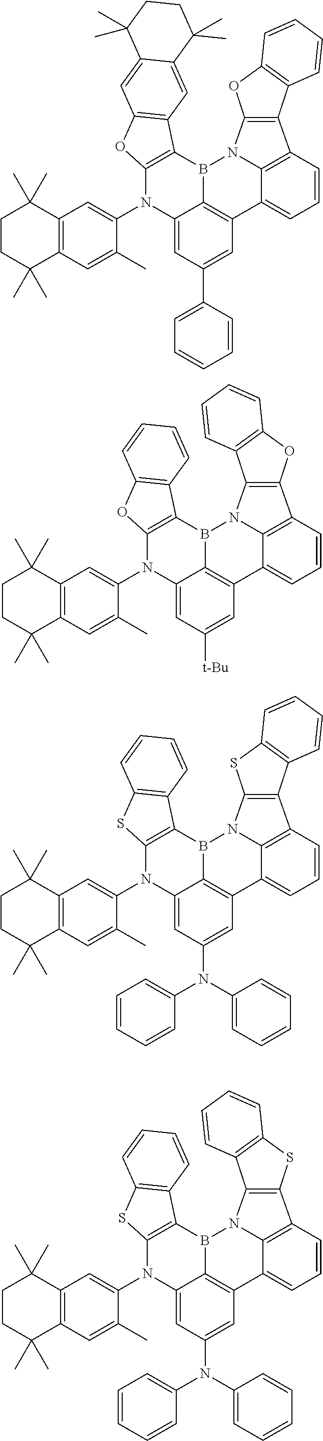 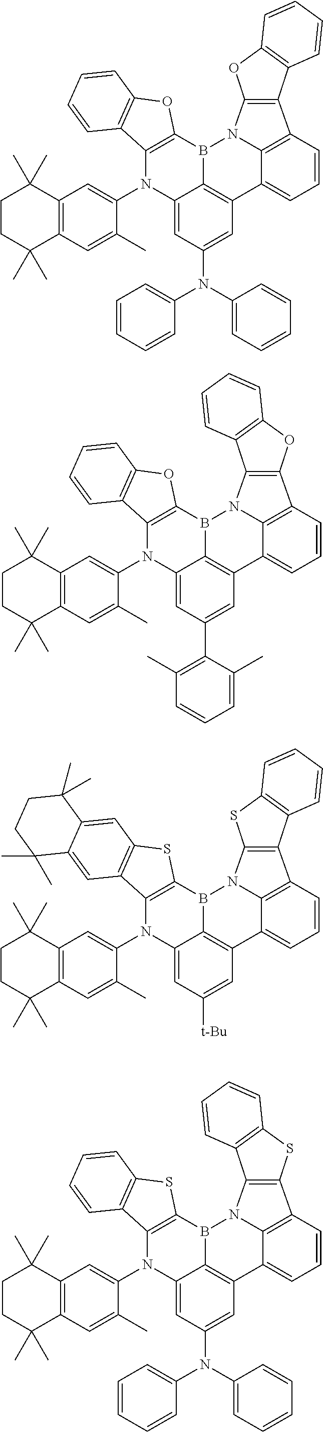 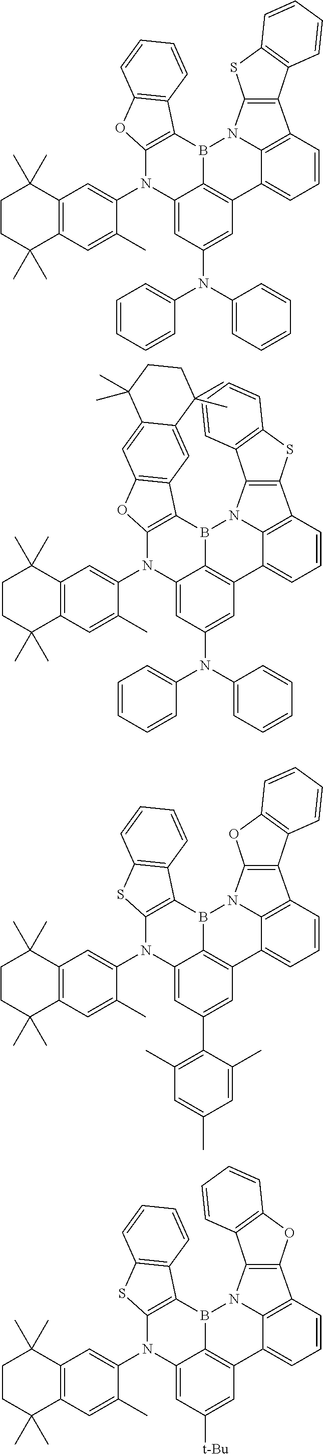 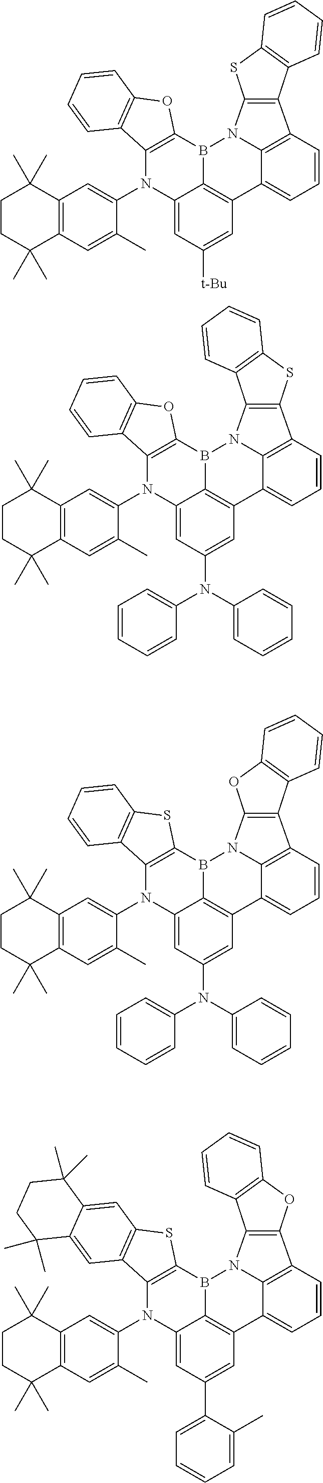 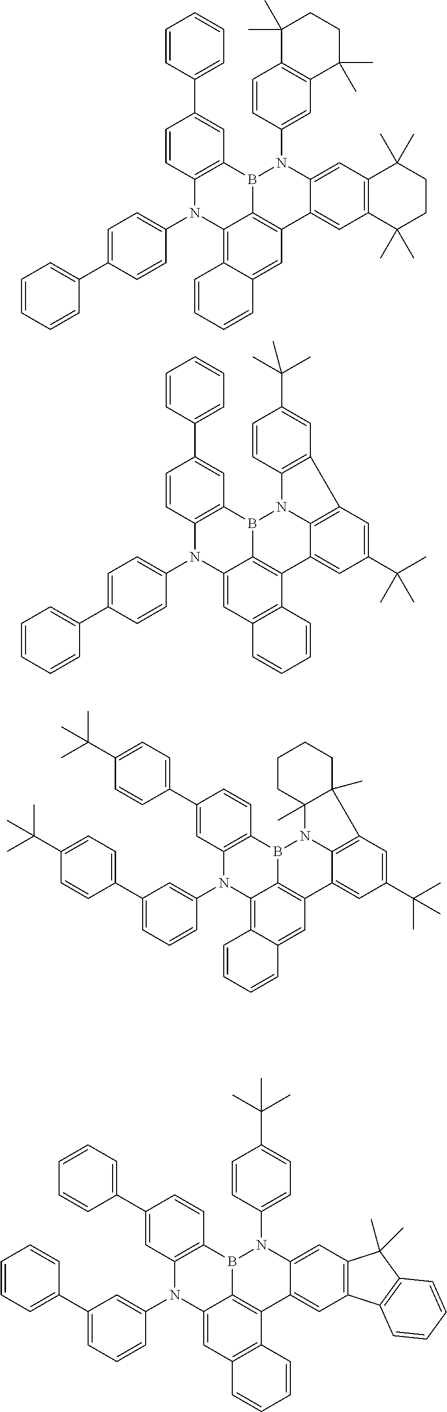 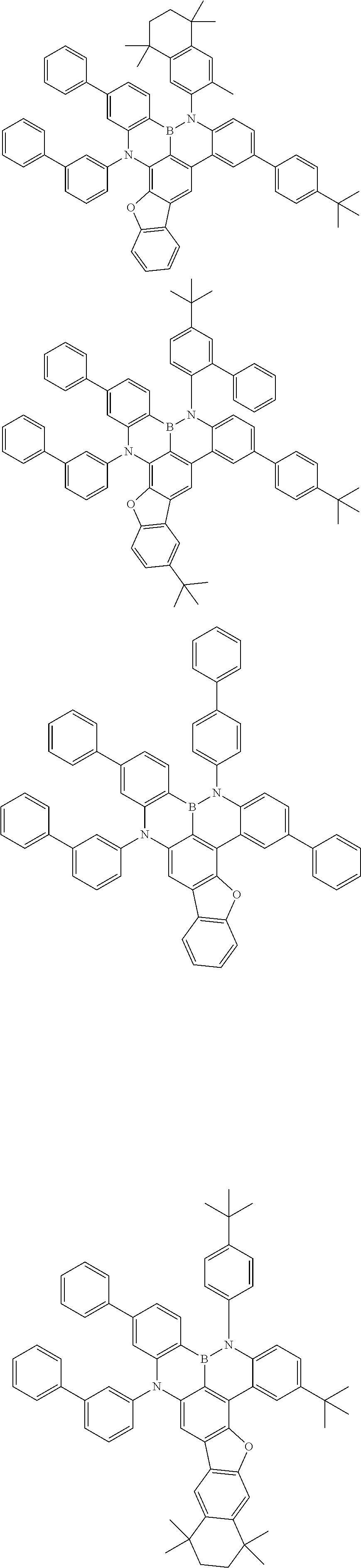 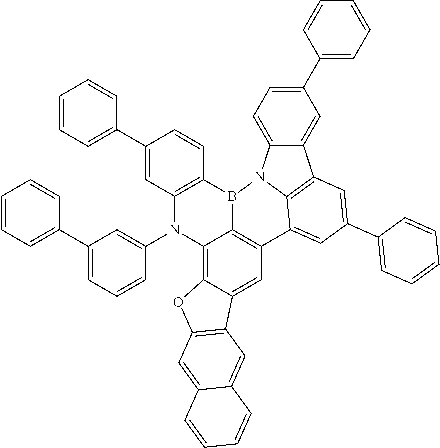 [SMILES: c1ccc(-c2cccc(N3c4cc(-c5ccccc5)ccc4B4c5c(cc6c(oc7cc8ccccc8cc76)c53)-c3cc(-c5ccccc5)cc5c6cc(-c7ccccc7)ccc6n4c35)c2)cc1] 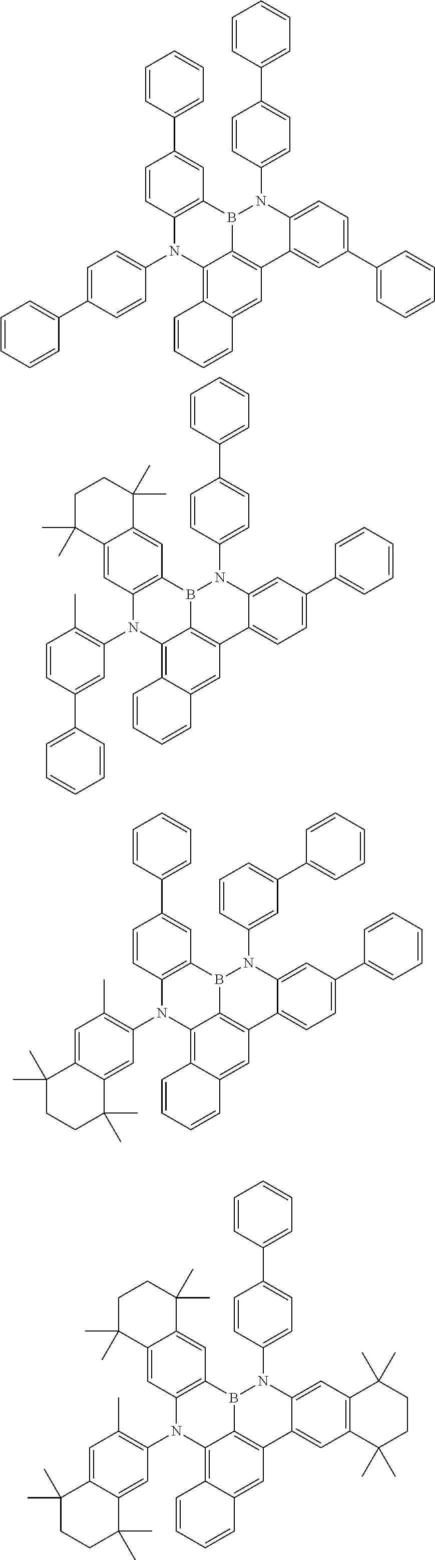 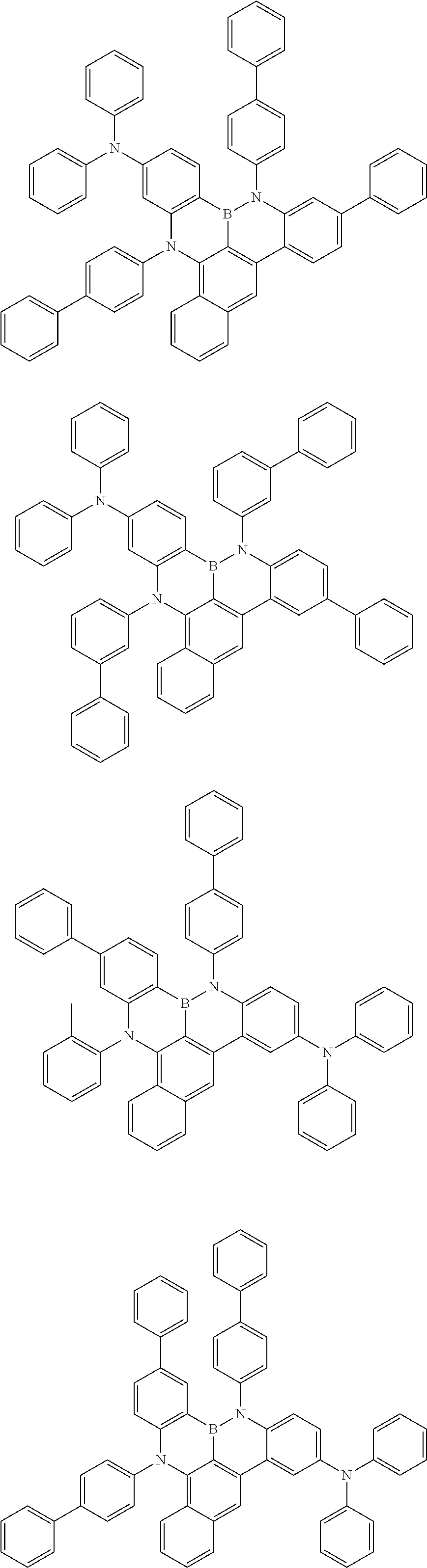 [SMILES: c1ccc(-c2ccc(N3B4c5ccc(N(c6ccccc6)c6ccccc6)cc5N(c5ccc(-c6ccccc6)cc5)c5c4c(cc4ccccc54)-c4ccc(-c5ccccc5)cc43)cc2)cc1 ; c1ccc(-c2cccc(N3B4c5ccc(N(c6ccccc6)c6ccccc6)cc5N(c5cccc(-c6ccccc6)c5)c5c4c(cc4ccccc54)-c4cc(-c5ccccc5)ccc43)c2)cc1 ; Cc1ccccc1N1c2cc(-c3ccccc3)ccc2B2c3c(cc4ccccc4c31)-c1cc(N(c3ccccc3)c3ccccc3)ccc1N2c1ccc(-c2ccccc2)cc1 ; c1ccc(-c2ccc(N3B4c5cc(-c6ccccc6)ccc5N(c5ccc(-c6ccccc6)cc5)c5c4c(cc4ccccc54)-c4cc(N(c5ccccc5)c5ccccc5)ccc43)cc2)cc1] 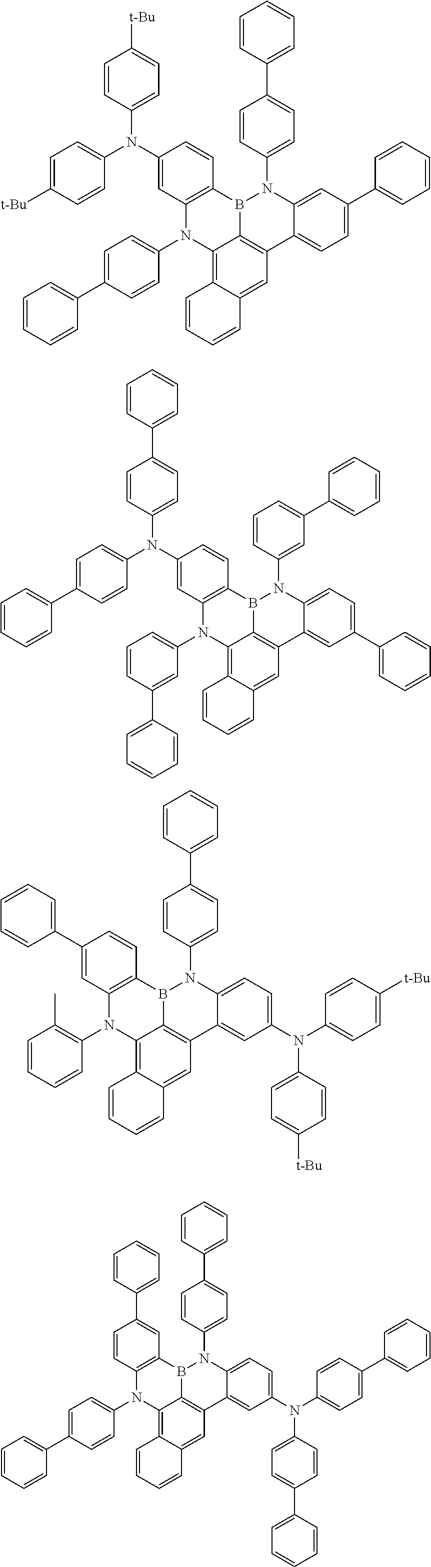 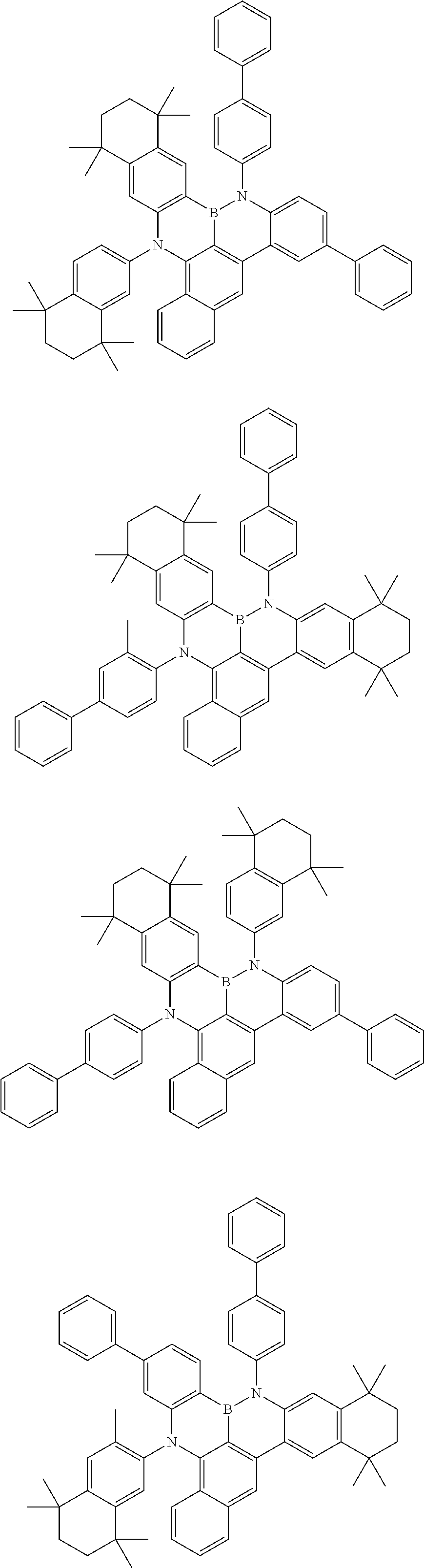 [SMILES: CC1(C)CCC(C)(C)c2cc(N3c4cc5c(cc4B4c6c(cc7ccccc7c63)-c3cc(-c6ccccc6)ccc3N4c3ccc(-c4ccccc4)cc3)C(C)(C)CCC5(C)C)ccc21 ; Cc1cc(-c2ccccc2)ccc1N1c2cc3c(cc2B2c4c(cc5ccccc5c41)-c1cc4c(cc1N2c1ccc(-c2ccccc2)cc1)C(C)(C)CCC4(C)C)C(C)(C)CCC3(C)C ; CC1(C)CCC(C)(C)c2cc(N3B4c5cc6c(cc5N(c5ccc(-c7ccccc7)cc5)c5c4c(cc4ccccc54)-c4cc(-c5ccccc5)ccc43)C(C)(C)CCC6(C)C)ccc21 ; Cc1cc2c(cc1N1c3cc(-c4ccccc4)ccc3B3c4c(cc5ccccc5c41)-c1cc4c(cc1N3c1ccc(-c3ccccc3)cc1)C(C)(C)CCC4(C)C)C(C)(C)CCC2(C)C] 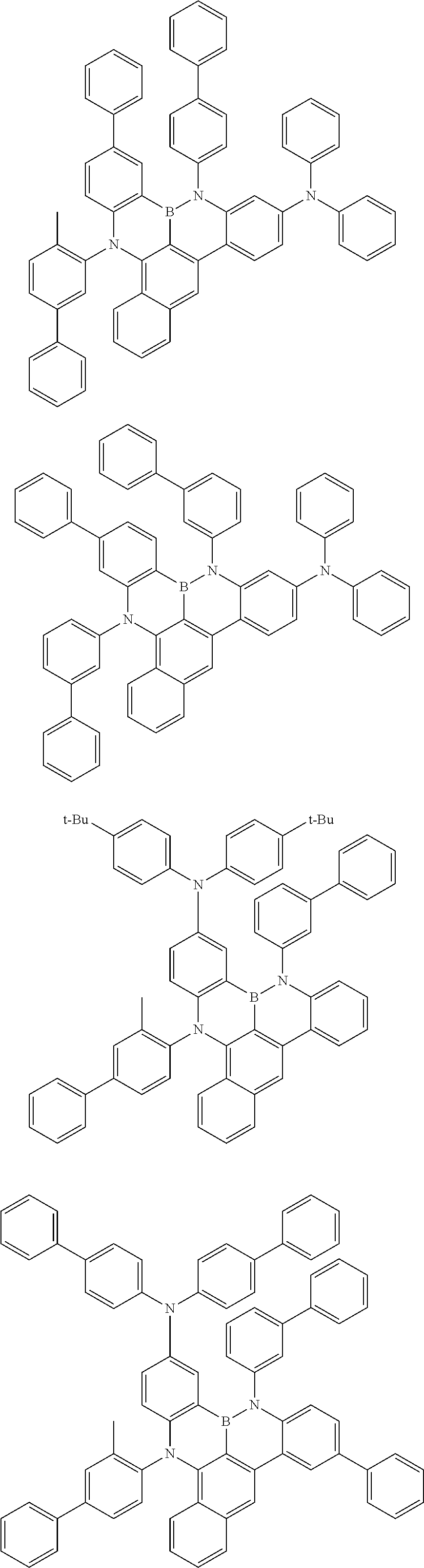 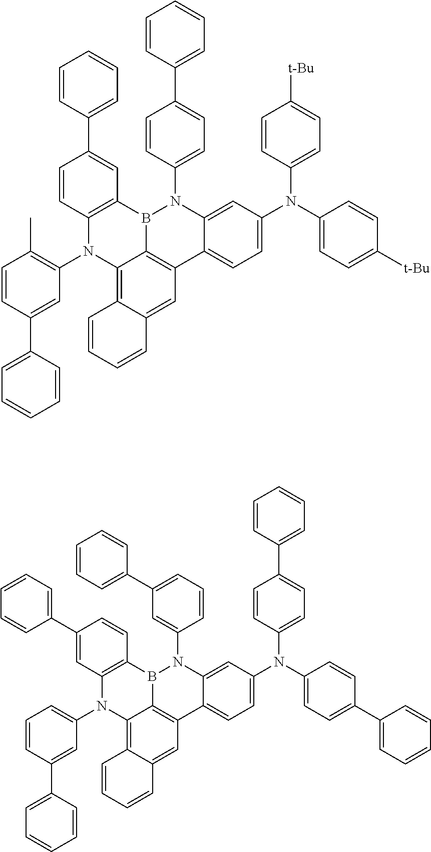 [SMILES: Cc1ccc(-c2ccccc2)cc1N1c2ccc(-c3ccccc3)cc2B2c3c(cc4ccccc4c31)-c1ccc(N(c3ccc(C(C)(C)C)cc3)c3ccc(C(C)(C)C)cc3)cc1N2c1ccc(-c2ccccc2)cc1 ; c1ccc(-c2ccc(N(c3ccc(-c4ccccc4)cc3)c3ccc4c(c3)N(c3cccc(-c5ccccc5)c3)B3c5ccc(-c6ccccc6)cc5N(c5cccc(-c6ccccc6)c5)c5c3c-4cc3ccccc53)cc2)cc1] 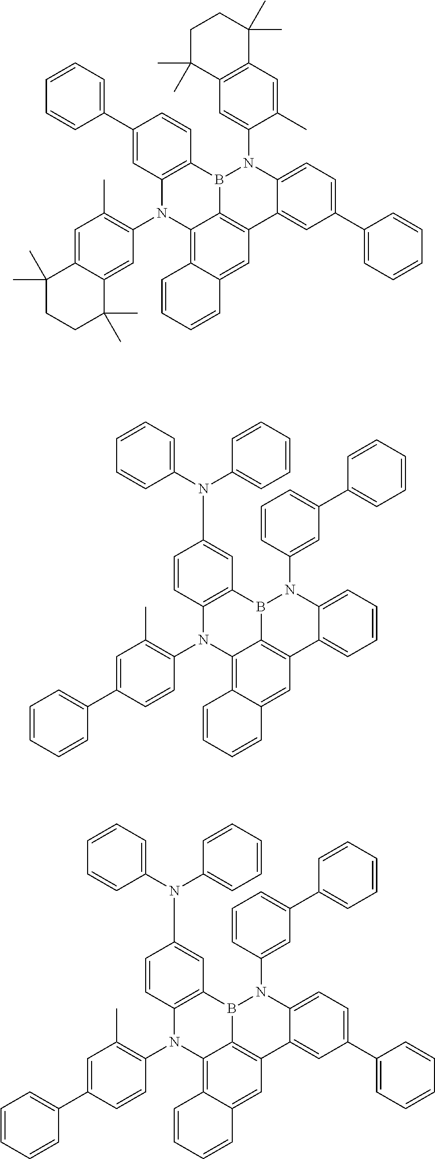 [SMILES: Cc1cc2c(cc1N1B3c4ccc(-c5ccccc5)cc4N(c4cc5c(cc4C)C(C)(C)CCC5(C)C)c4c3c(cc3ccccc43)-c3cc(-c4ccccc4)ccc31)C(C)(C)CCC2(C)C ; Cc1cc(-c2ccccc2)ccc1N1c2ccc(N(c3ccccc3)c3ccccc3)cc2B2c3c(cc4ccccc4c31)-c1ccccc1N2c1cccc(-c2ccccc2)c1 ; Cc1cc(-c2ccccc2)ccc1N1c2ccc(N(c3ccccc3)c3ccccc3)cc2B2c3c(cc4ccccc4c31)-c1cc(-c3ccccc3)ccc1N2c1cccc(-c2ccccc2)c1] 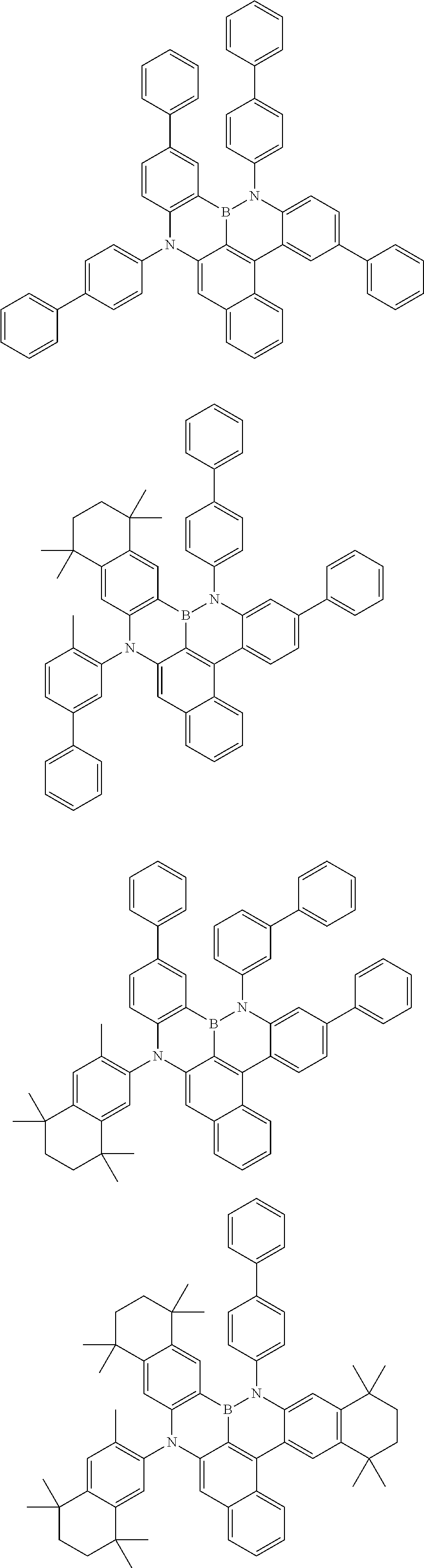 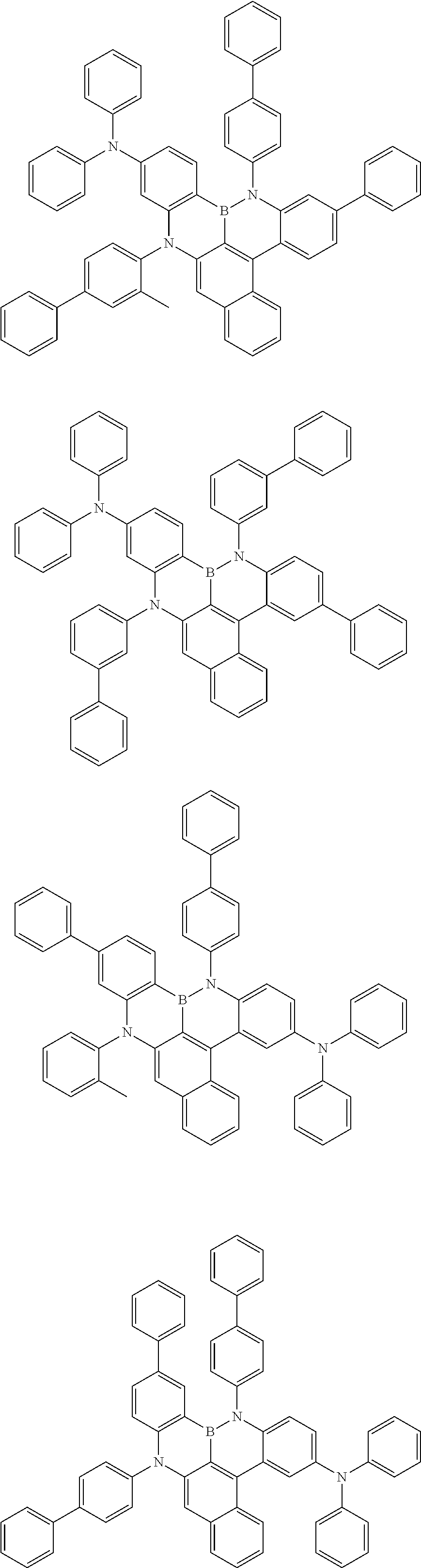 [SMILES: Cc1cc(-c2ccccc2)ccc1N1c2cc(N(c3ccccc3)c3ccccc3)ccc2B2c3c1cc1ccccc1c3-c1ccc(-c3ccccc3)cc1N2c1ccc(-c2ccccc2)cc1 ; c1ccc(-c2cccc(N3B4c5ccc(N(c6ccccc6)c6ccccc6)cc5N(c5cccc(-c6ccccc6)c5)c5cc6ccccc6c(c54)-c4cc(-c5ccccc5)ccc43)c2)cc1 ; Cc1ccccc1N1c2cc(-c3ccccc3)ccc2B2c3c1cc1ccccc1c3-c1cc(N(c3ccccc3)c3ccccc3)ccc1N2c1ccc(-c2ccccc2)cc1 ; c1ccc(-c2ccc(N3B4c5cc(-c6ccccc6)ccc5N(c5ccc(-c6ccccc6)cc5)c5cc6ccccc6c(c54)-c4cc(N(c5ccccc5)c5ccccc5)ccc43)cc2)cc1] 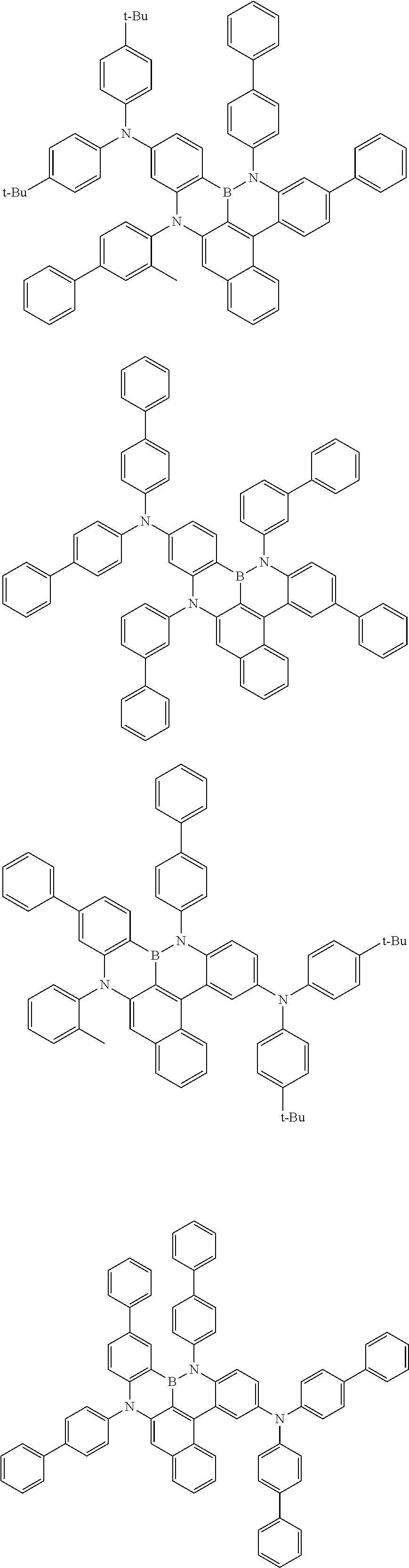 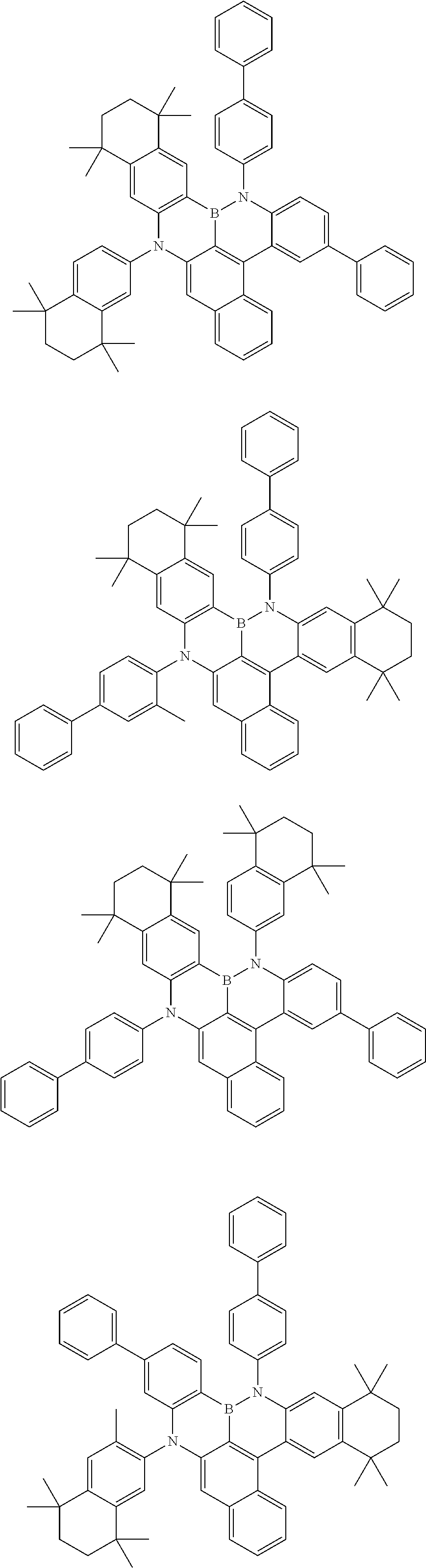 [SMILES: CC1(C)CCC(C)(C)c2cc(N3c4cc5c(cc4B4c6c3cc3ccccc3c6-c3cc(-c6ccccc6)ccc3N4c3ccc(-c4ccccc4)cc3)C(C)(C)CCC5(C)C)ccc21 ; Cc1cc(-c2ccccc2)ccc1N1c2cc3c(cc2B2c4c1cc1ccccc1c4-c1cc4c(cc1N2c1ccc(-c2ccccc2)cc1)C(C)(C)CCC4(C)C)C(C)(C)CCC3(C)C ; CC1(C)CCC(C)(C)c2cc(N3B4c5cc6c(cc5N(c5ccc(-c7ccccc7)cc5)c5cc7ccccc7c(c54)-c4cc(-c5ccccc5)ccc43)C(C)(C)CCC6(C)C)ccc21 ; Cc1cc2c(cc1N1c3cc(-c4ccccc4)ccc3B3c4c1cc1ccccc1c4-c1cc4c(cc1N3c1ccc(-c3ccccc3)cc1)C(C)(C)CCC4(C)C)C(C)(C)CCC2(C)C] 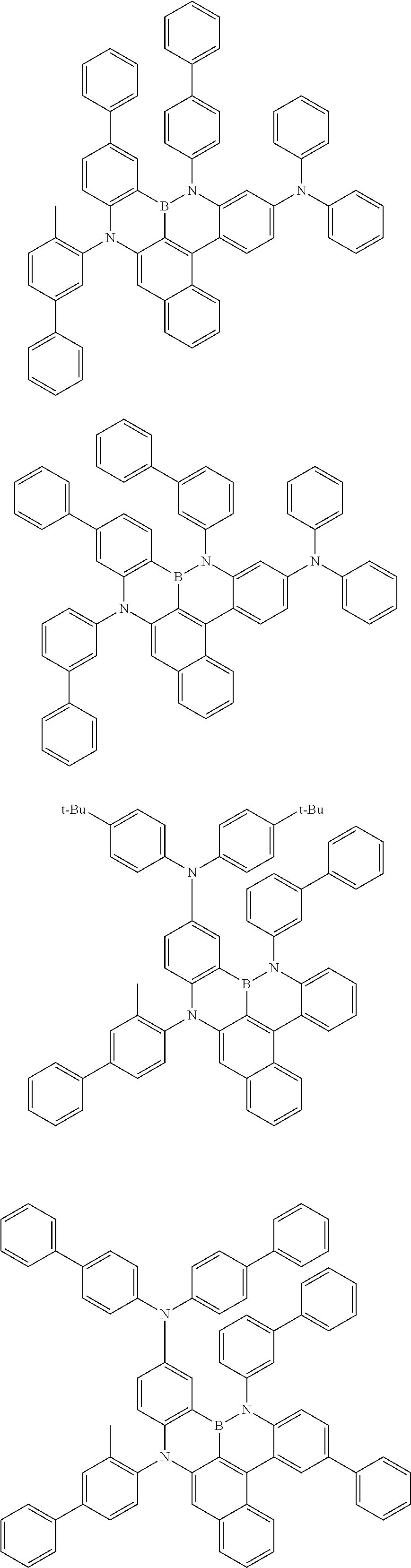 [SMILES: Cc1ccc(-c2ccccc2)cc1N1c2ccc(-c3ccccc3)cc2B2c3c1cc1ccccc1c3-c1ccc(N(c3ccccc3)c3ccccc3)cc1N2c1ccc(-c2ccccc2)cc1 ; c1ccc(-c2cccc(N3B4c5ccc(-c6ccccc6)cc5N(c5cccc(-c6ccccc6)c5)c5cc6ccccc6c(c54)-c4ccc(N(c5ccccc5)c5ccccc5)cc43)c2)cc1 ; Cc1cc(-c2ccccc2)ccc1N1c2ccc(N(c3ccc(C(C)(C)C)cc3)c3ccc(C(C)(C)C)cc3)cc2B2c3c1cc1ccccc1c3-c1ccccc1N2c1cccc(-c2ccccc2)c1 ; Cc1cc(-c2ccccc2)ccc1N1c2ccc(N(c3ccc(-c4ccccc4)cc3)c3ccc(-c4ccccc4)cc3)cc2B2c3c1cc1ccccc1c3-c1cc(-c3ccccc3)ccc1N2c1cccc(-c2ccccc2)c1] 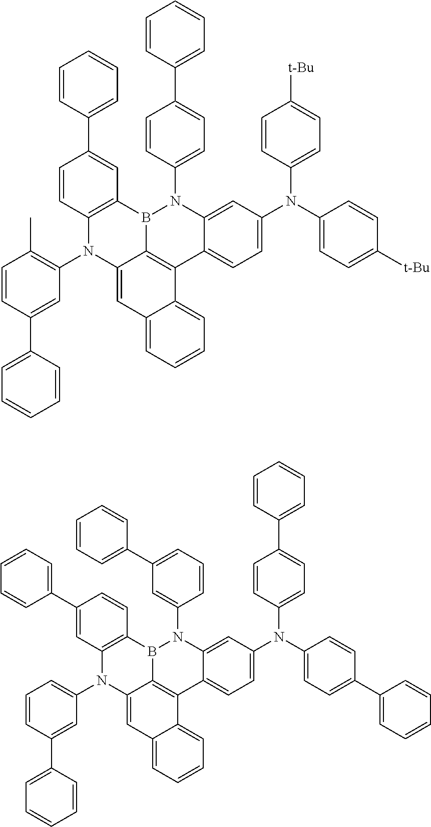 [SMILES: Cc1ccc(-c2ccccc2)cc1N1c2ccc(-c3ccccc3)cc2B2c3c1cc1ccccc1c3-c1ccc(N(c3ccc(C(C)(C)C)cc3)c3ccc(C(C)(C)C)cc3)cc1N2c1ccc(-c2ccccc2)cc1 ; c1ccc(-c2ccc(N(c3ccc(-c4ccccc4)cc3)c3ccc4c(c3)N(c3cccc(-c5ccccc5)c3)B3c5ccc(-c6ccccc6)cc5N(c5cccc(-c6ccccc6)c5)c5cc6ccccc6c-4c53)cc2)cc1] 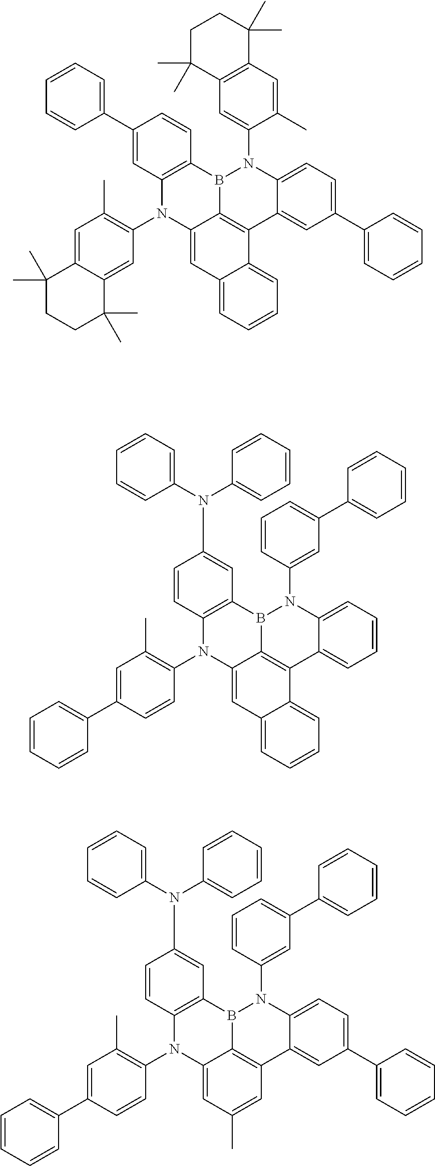 [SMILES: Cc1cc2c(cc1N1B3c4ccc(-c5ccccc5)cc4N(c4cc5c(cc4C)C(C)(C)CCC5(C)C)c4cc5ccccc5c(c43)-c3cc(-c4ccccc4)ccc31)C(C)(C)CCC2(C)C ; Cc1cc(-c2ccccc2)ccc1N1c2ccc(N(c3ccccc3)c3ccccc3)cc2B2c3c1cc1ccccc1c3-c1ccccc1N2c1cccc(-c2ccccc2)c1 ; Cc1cc2c3c(c1)N(c1ccc(-c4ccccc4)cc1C)c1ccc(N(c4ccccc4)c4ccccc4)cc1B3N(c1cccc(-c3ccccc3)c1)c1ccc(-c3ccccc3)cc1-2] 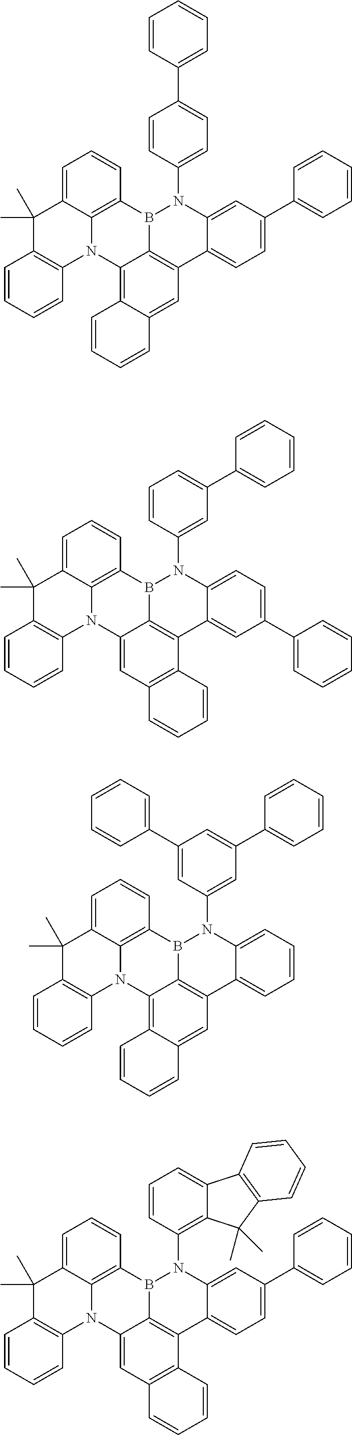 [SMILES: CC1(C)c2ccccc2N2c3c(cccc31)B1c3c(cc4ccccc4c32)-c2ccc(-c3ccccc3)cc2N1c1ccc(-c2ccccc2)cc1 ; CC1(C)c2ccccc2N2c3cc4ccccc4c4c3B(c3cccc1c32)N(c1cccc(-c2ccccc2)c1)c1ccc(-c2ccccc2)cc1-4 ; CC1(C)c2ccccc2N2c3c(cccc31)B1c3c(cc4ccccc4c32)-c2ccccc2N1c1cc(-c2ccccc2)cc(-c2ccccc2)c1 ; CC1(C)c2ccccc2N2c3cc4ccccc4c4c3B(c3cccc1c32)N(c1cccc2c1C(C)(C)c1ccccc1-2)c1cc(-c2ccccc2)ccc1-4] 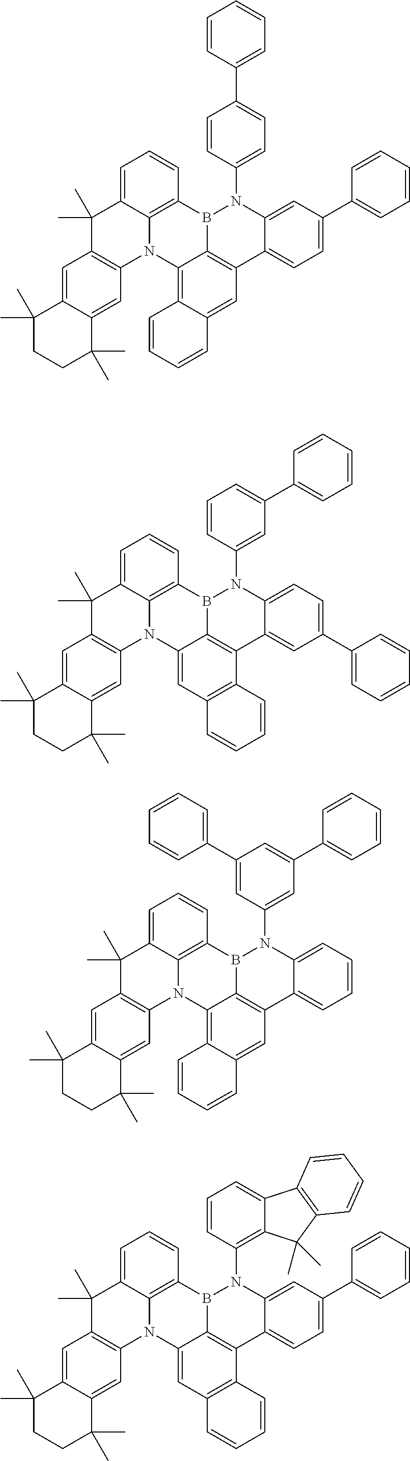 [SMILES: CC1(C)CCC(C)(C)c2cc3c(cc21)N1c2c(cccc2C3(C)C)B2c3c(cc4ccccc4c31)-c1ccc(-c3ccccc3)cc1N2c1ccc(-c2ccccc2)cc1 ; CC1(C)CCC(C)(C)c2cc3c(cc21)N1c2cc4ccccc4c4c2B(c2cccc(c21)C3(C)C)N(c1cccc(-c2ccccc2)c1)c1ccc(-c2ccccc2)cc1-4 ; CC1(C)CCC(C)(C)c2cc3c(cc21)N1c2c(cccc2C3(C)C)B2c3c(cc4ccccc4c31)-c1ccccc1N2c1cc(-c2ccccc2)cc(-c2ccccc2)c1 ; CC1(C)CCC(C)(C)c2cc3c(cc21)N1c2cc4ccccc4c4c2B(c2cccc(c21)C3(C)C)N(c1cccc2c1C(C)(C)c1ccccc1-2)c1cc(-c2ccccc2)ccc1-4] 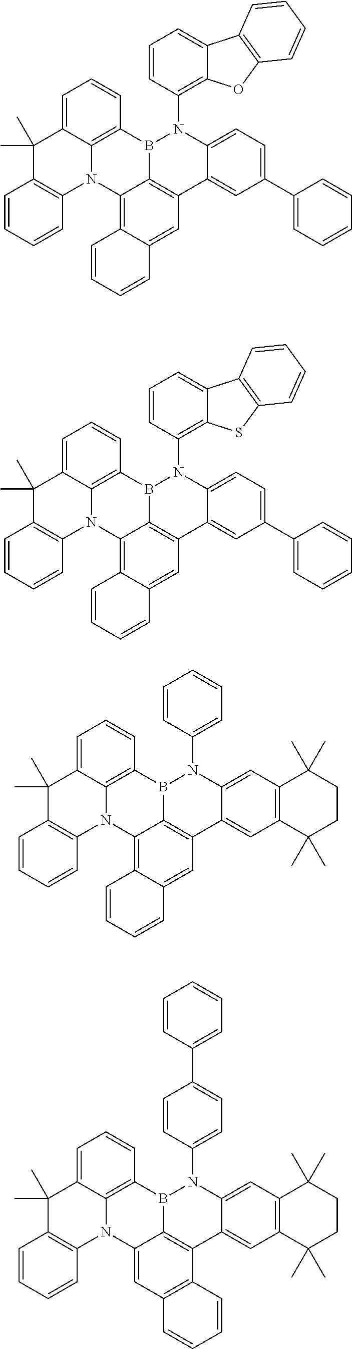 [SMILES: CC1(C)c2ccccc2N2c3c(cccc31)B1c3c(cc4ccccc4c32)-c2cc(-c3ccccc3)ccc2N1c1cccc2c1oc1ccccc12 ; CC1(C)c2ccccc2N2c3c(cccc31)B1c3c(cc4ccccc4c32)-c2cc(-c3ccccc3)ccc2N1c1cccc2c1sc1ccccc12 ; CC1(C)CCC(C)(C)c2cc3c(cc21)-c1cc2ccccc2c2c1B(c1cccc4c1N2c1ccccc1C4(C)C)N3c1ccccc1 ; CC1(C)CCC(C)(C)c2cc3c(cc21)-c1c2c(cc4ccccc14)N1c4ccccc4C(C)(C)c4cccc(c41)B2N3c1ccc(-c2ccccc2)cc1] 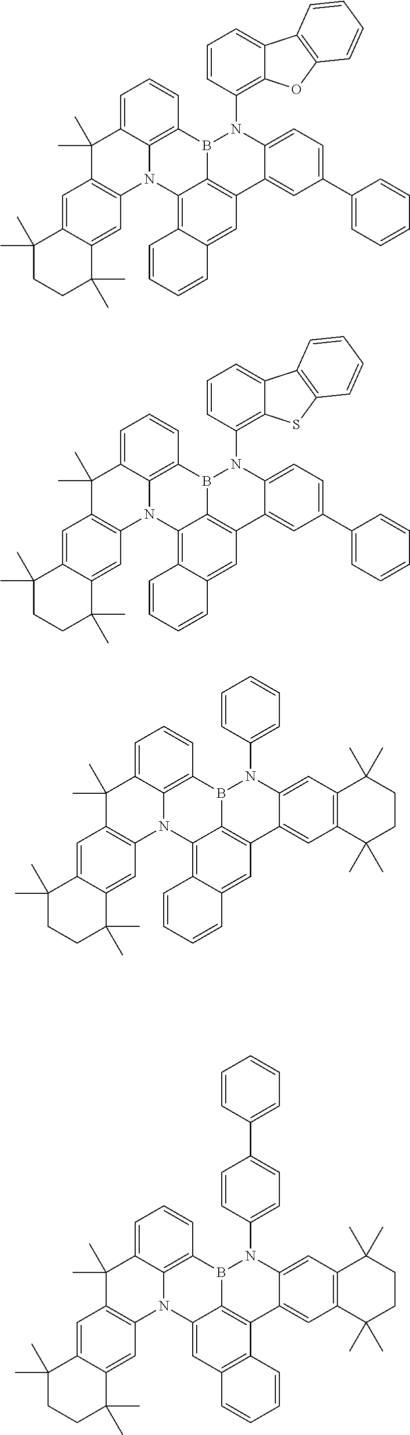 [SMILES: CC1(C)CCC(C)(C)c2cc3c(cc21)N1c2c(cccc2C3(C)C)B2c3c(cc4ccccc4c31)-c1cc(-c3ccccc3)ccc1N2c1cccc2c1oc1ccccc12 ; CC1(C)CCC(C)(C)c2cc3c(cc21)N1c2c(cccc2C3(C)C)B2c3c(cc4ccccc4c31)-c1cc(-c3ccccc3)ccc1N2c1cccc2c1sc1ccccc12 ; CC1(C)CCC(C)(C)c2cc3c(cc21)-c1cc2ccccc2c2c1B(c1cccc4c1N2c1cc2c(cc1C4(C)C)C(C)(C)CCC2(C)C)N3c1ccccc1 ; CC1(C)CCC(C)(C)c2cc3c(cc21)-c1c2c(cc4ccccc14)N1c4cc5c(cc4C(C)(C)c4cccc(c41)B2N3c1ccc(-c2ccccc2)cc1)C(C)(C)CCC5(C)C] 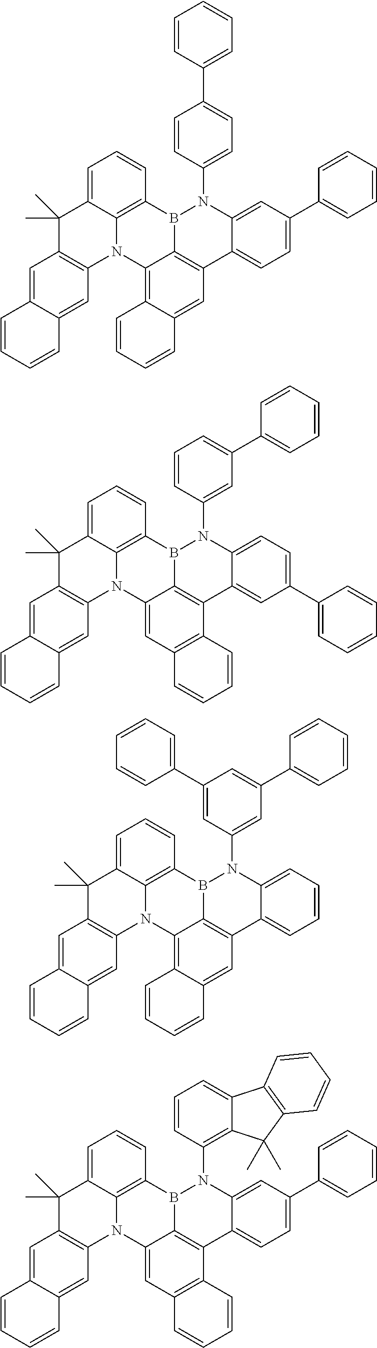 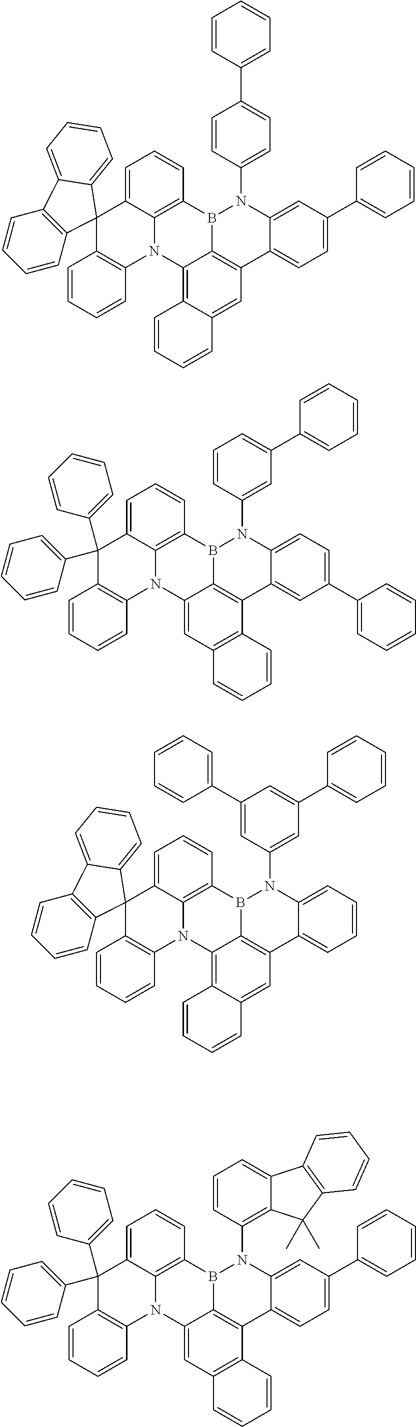 [SMILES: c1ccc(-c2ccc(N3B4c5cccc6c5N(c5ccccc5C65c6ccccc6-c6ccccc65)c5c4c(cc4ccccc54)-c4ccc(-c5ccccc5)cc43)cc2)cc1 ; c1ccc(-c2cccc(N3B4c5cccc6c5N(c5ccccc5C6(c5ccccc5)c5ccccc5)c5cc6ccccc6c(c54)-c4cc(-c5ccccc5)ccc43)c2)cc1 ; c1ccc(-c2cc(-c3ccccc3)cc(N3B4c5cccc6c5N(c5ccccc5C65c6ccccc6-c6ccccc65)c5c4c(cc4ccccc54)-c4ccccc43)c2)cc1 ; CC1(C)c2ccccc2-c2cccc(N3B4c5cccc6c5N(c5ccccc5C6(c5ccccc5)c5ccccc5)c5cc6ccccc6c(c54)-c4ccc(-c5ccccc5)cc43)c21] 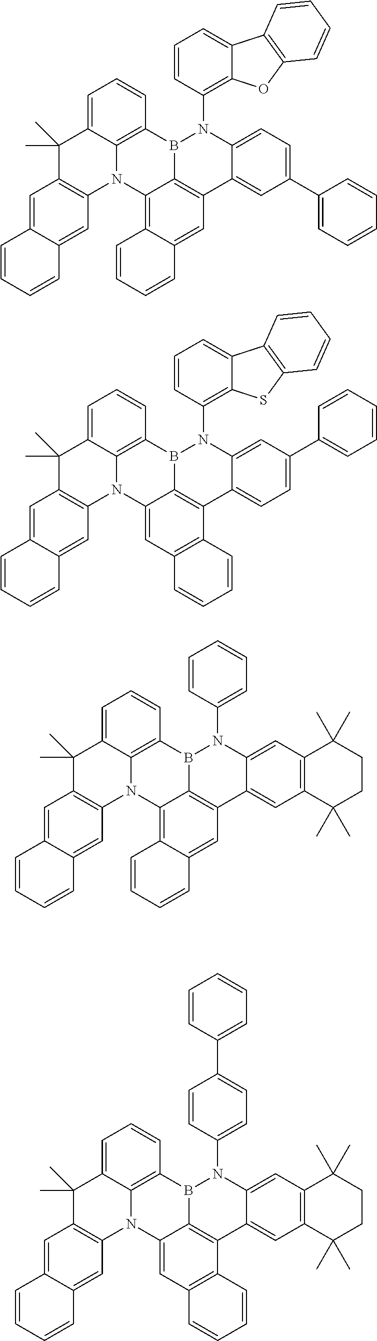 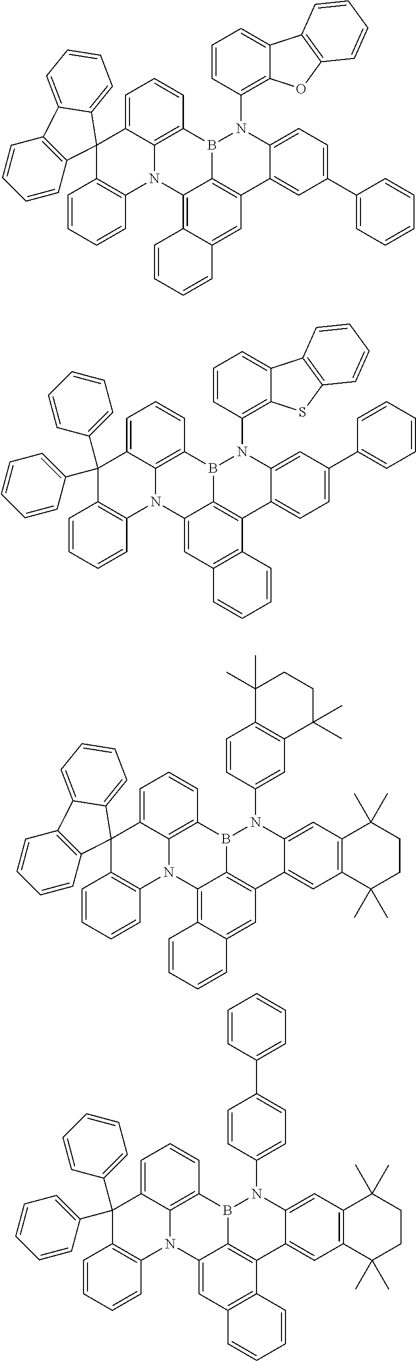 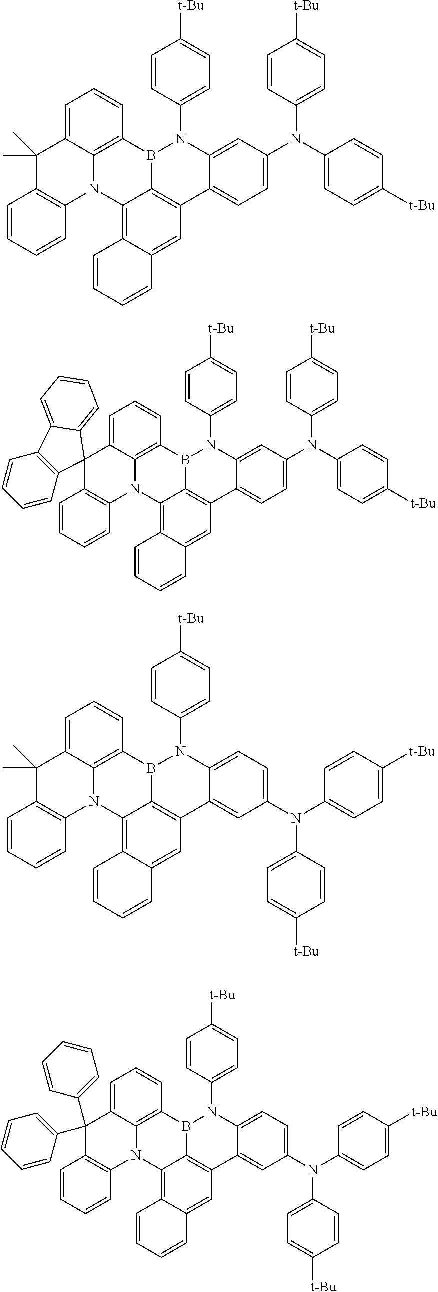 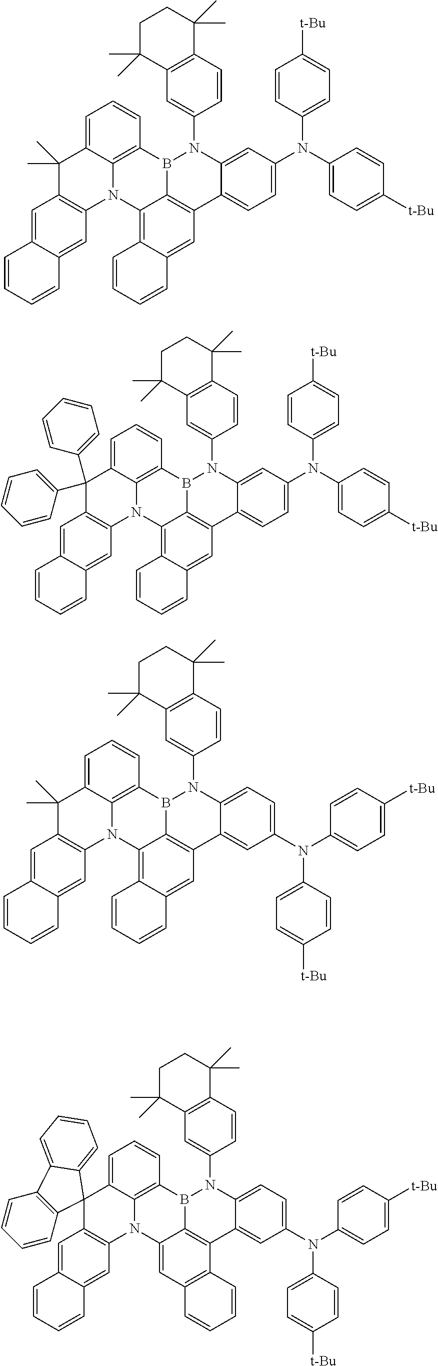 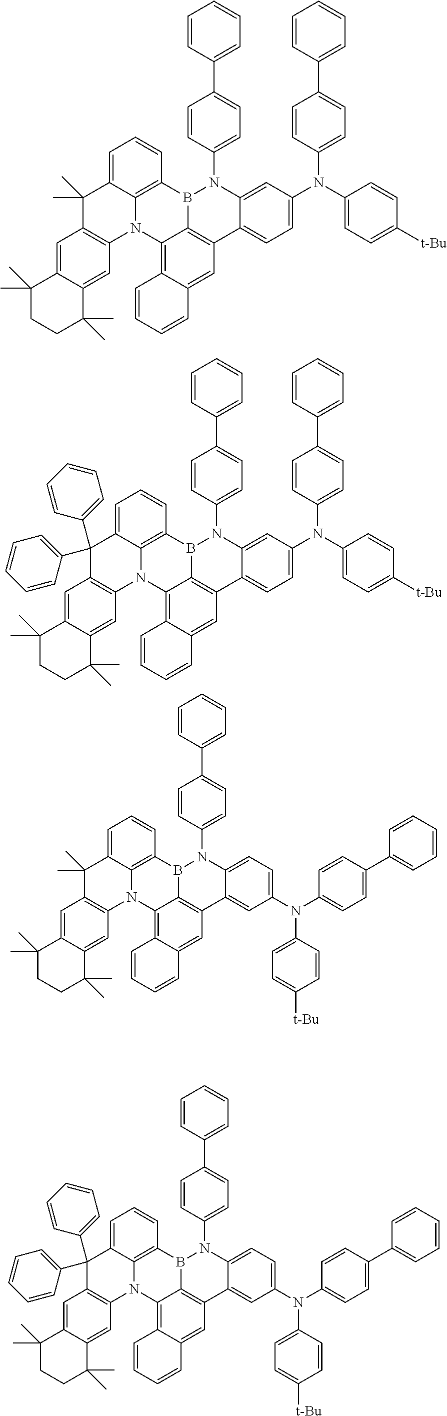 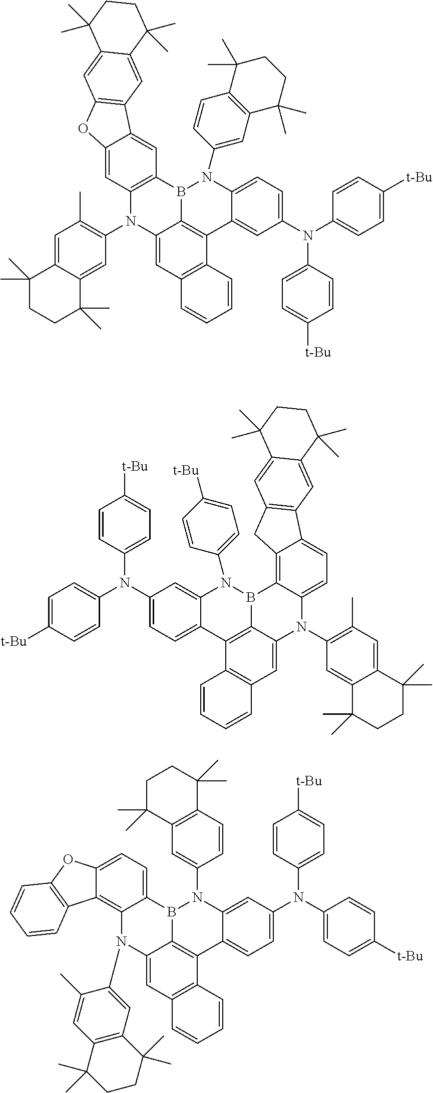 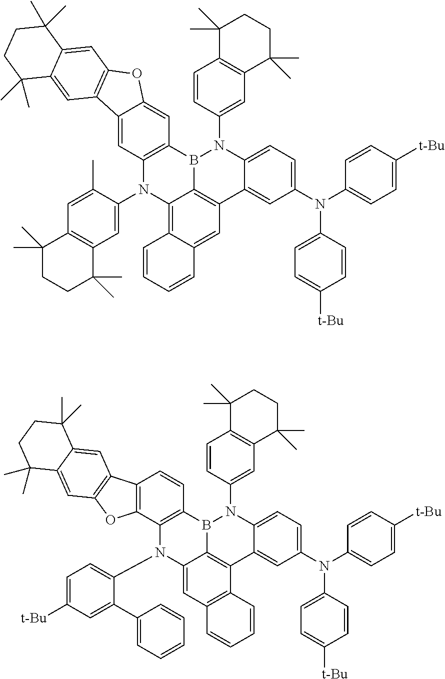 [SMILES: Cc1cc2c(cc1N1c3cc4c(cc3B3c5c(cc6ccccc6c51)-c1cc(N(c5ccc(C(C)(C)C)cc5)c5ccc(C(C)(C)C)cc5)ccc1N3c1ccc3c(c1)C(C)(C)CCC3(C)C)oc1cc3c(cc14)C(C)(C)CCC3(C)C)C(C)(C)CCC2(C)C ; CC(C)(C)c1ccc(N(c2ccc(C(C)(C)C)cc2)c2ccc3c(c2)-c2c4c(cc5ccccc25)N(c2ccc(C(C)(C)C)cc2-c2ccccc2)c2c(ccc5c2oc2cc6c(cc25)C(C)(C)CCC6(C)C)B4N3c2ccc3c(c2)C(C)(C)CCC3(C)C)cc1] 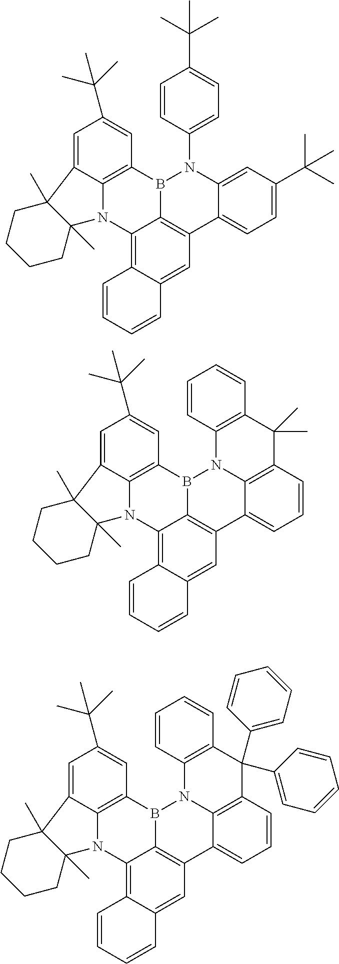 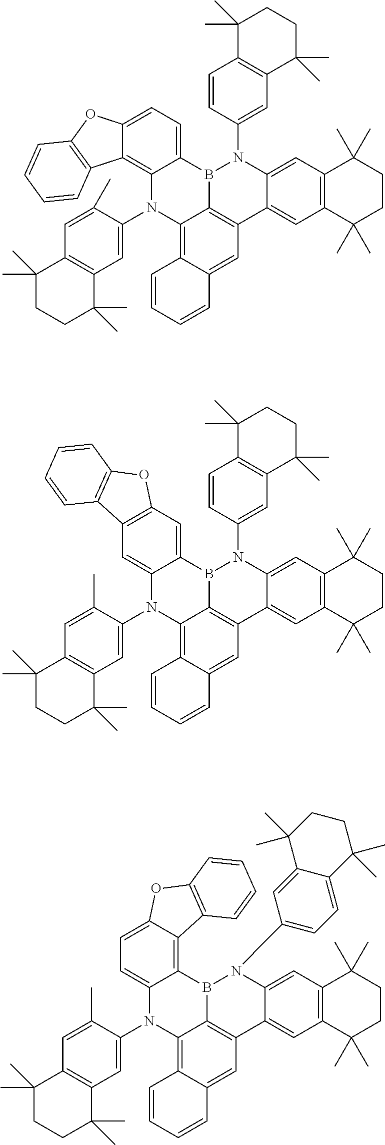 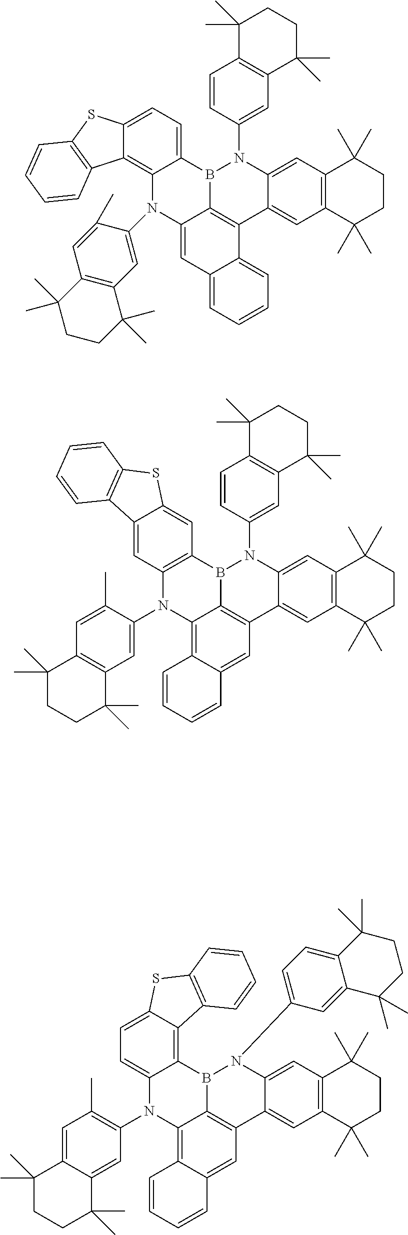 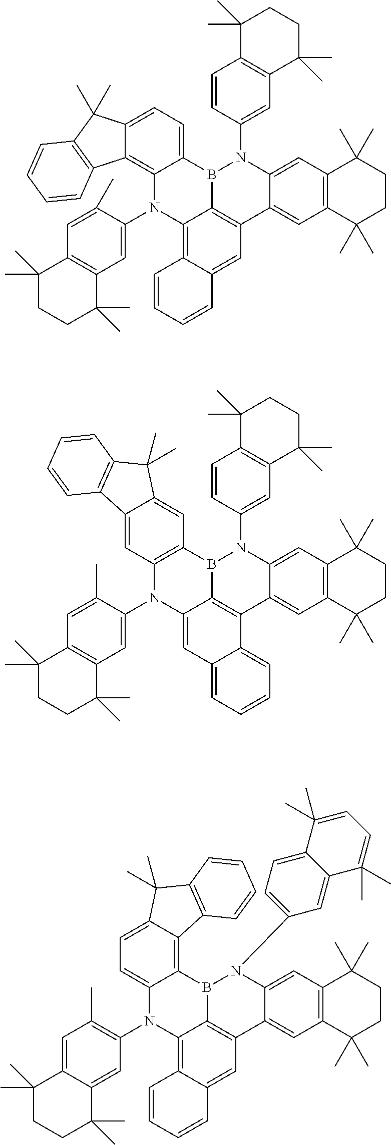 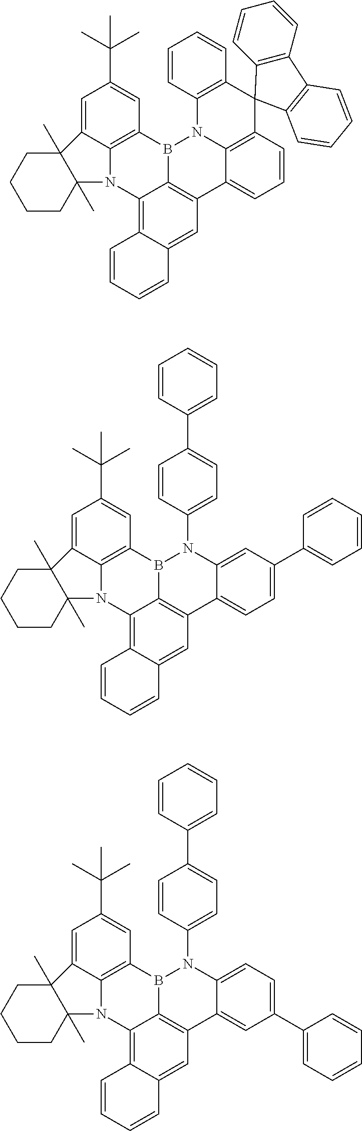 [SMILES: CC(C)(C)c1cc2c3c(c1)C1(C)CCCCC1(C)N3c1c3c(cc4ccccc14)-c1cccc4c1N(B23)c1ccccc1C41c2ccccc2-c2ccccc21 ; CC(C)(C)c1cc2c3c(c1)C1(C)CCCCC1(C)N3c1c3c(cc4ccccc14)-c1ccc(-c4ccccc4)cc1N(c1ccc(-c4ccccc4)cc1)B23 ; CC(C)(C)c1cc2c3c(c1)C1(C)CCCCC1(C)N3c1c3c(cc4ccccc14)-c1cc(-c4ccccc4)ccc1N(c1ccc(-c4ccccc4)cc1)B23] 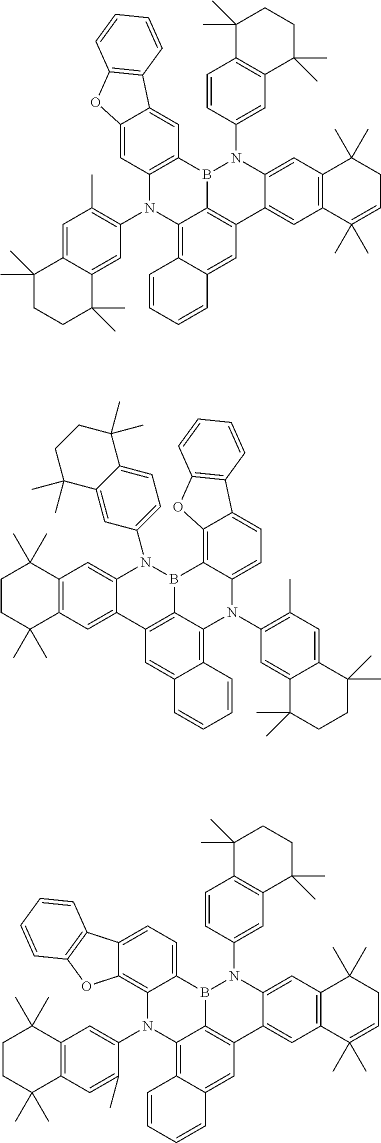 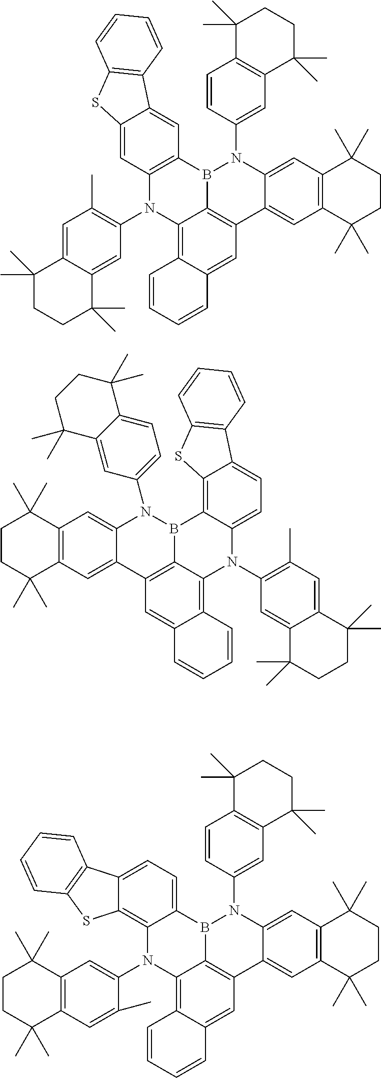 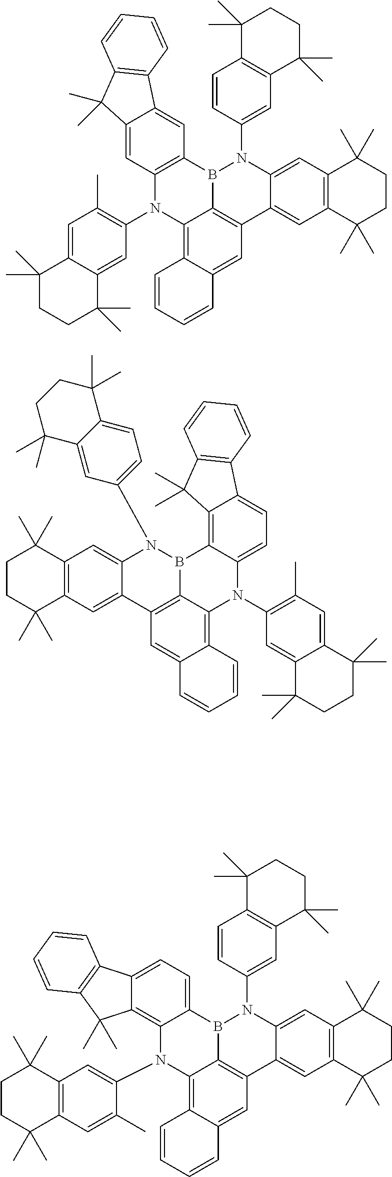 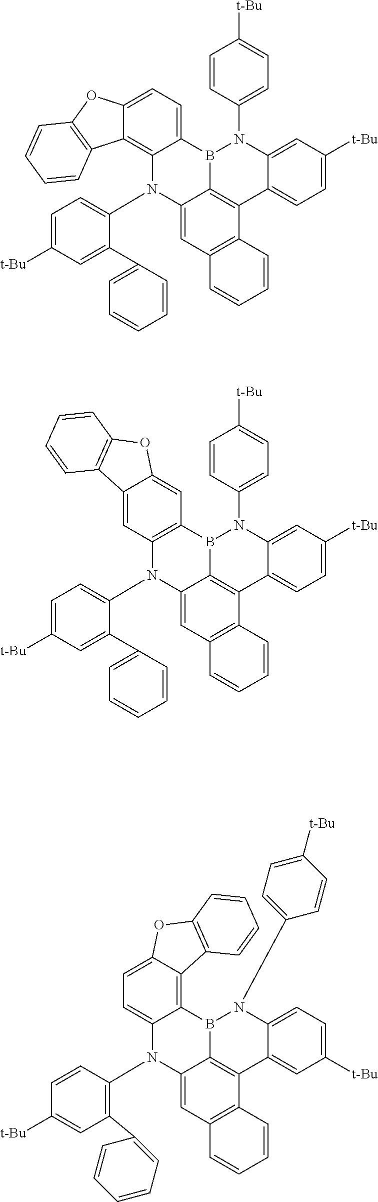 [SMILES: CC(C)(C)c1ccc(N2B3c4ccc5oc6ccccc6c5c4N(c4ccc(C(C)(C)C)cc4-c4ccccc4)c4cc5ccccc5c(c43)-c3ccc(C(C)(C)C)cc32)cc1 ; CC(C)(C)c1ccc(N2B3c4cc5oc6ccccc6c5cc4N(c4ccc(C(C)(C)C)cc4-c4ccccc4)c4cc5ccccc5c(c43)-c3ccc(C(C)(C)C)cc32)cc1 ; CC(C)(C)c1ccc(N2B3c4c(cc5ccccc5c4-c4cc(C(C)(C)C)ccc42)N(c2ccc(C(C)(C)C)cc2-c2ccccc2)c2ccc4oc5ccccc5c4c23)cc1] 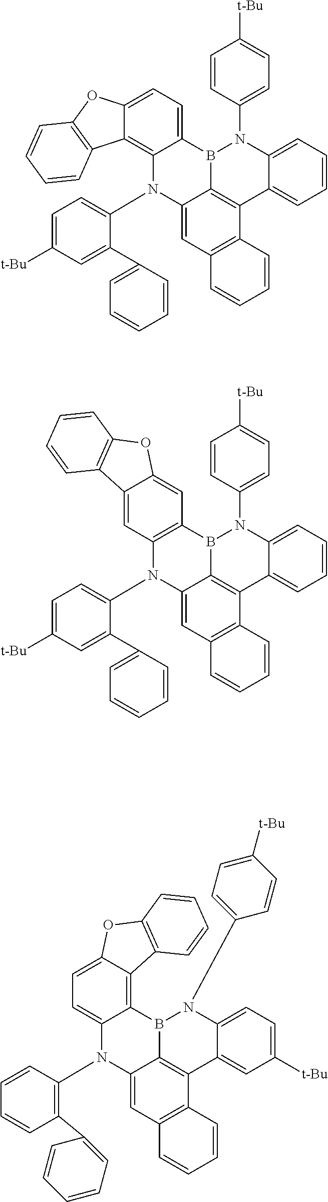 [SMILES: CC(C)(C)c1ccc(N2B3c4ccc5oc6ccccc6c5c4N(c4ccc(C(C)(C)C)cc4-c4ccccc4)c4cc5ccccc5c(c43)-c3ccccc32)cc1 ; CC(C)(C)c1ccc(N2B3c4cc5oc6ccccc6c5cc4N(c4ccc(C(C)(C)C)cc4-c4ccccc4)c4cc5ccccc5c(c43)-c3ccccc32)cc1 ; CC(C)(C)c1ccc(N2B3c4c(cc5ccccc5c4-c4cc(C(C)(C)C)ccc42)N(c2ccccc2-c2ccccc2)c2ccc4oc5ccccc5c4c23)cc1] 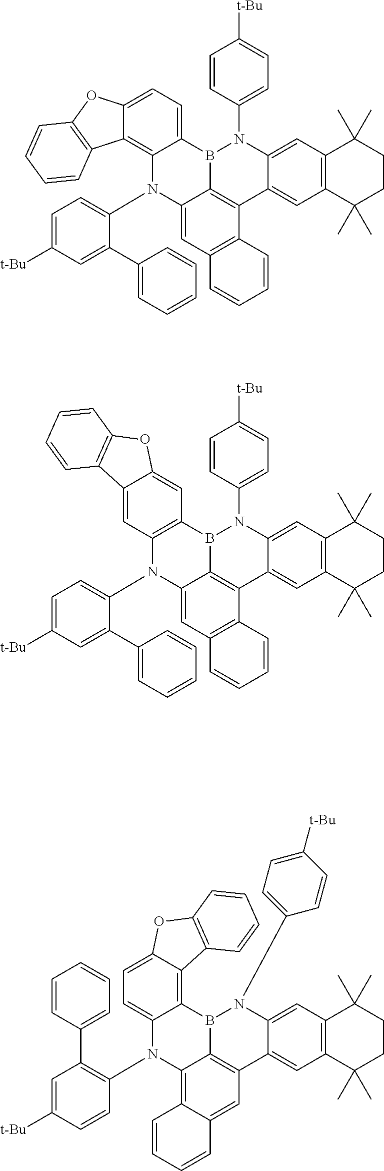 [SMILES: CC(C)(C)c1ccc(N2B3c4ccc5oc6ccccc6c5c4N(c4ccc(C(C)(C)C)cc4-c4ccccc4)c4cc5ccccc5c(c43)-c3cc4c(cc32)C(C)(C)CCC4(C)C)cc1 ; CC(C)(C)c1ccc(N2B3c4cc5oc6ccccc6c5cc4N(c4ccc(C(C)(C)C)cc4-c4ccccc4)c4cc5ccccc5c(c43)-c3cc4c(cc32)C(C)(C)CCC4(C)C)cc1 ; CC(C)(C)c1ccc(N2B3c4c(cc5ccccc5c4N(c4ccc(C(C)(C)C)cc4-c4ccccc4)c4ccc5oc6ccccc6c5c43)-c3cc4c(cc32)C(C)(C)CCC4(C)C)cc1] 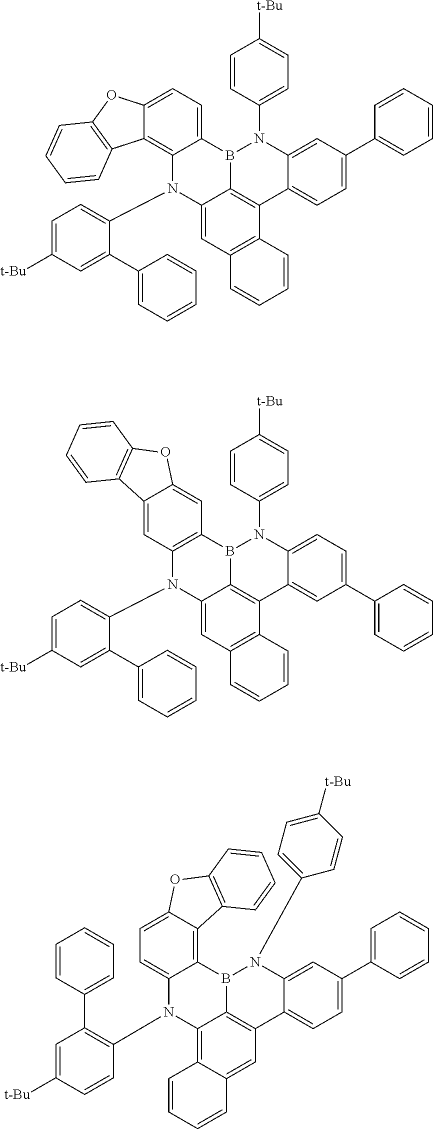 [SMILES: CC(C)(C)c1ccc(N2B3c4ccc5oc6ccccc6c5c4N(c4ccc(C(C)(C)C)cc4-c4ccccc4)c4cc5ccccc5c(c43)-c3ccc(-c4ccccc4)cc32)cc1 ; CC(C)(C)c1ccc(N2B3c4cc5oc6ccccc6c5cc4N(c4ccc(C(C)(C)C)cc4-c4ccccc4)c4cc5ccccc5c(c43)-c3cc(-c4ccccc4)ccc32)cc1 ; CC(C)(C)c1ccc(N2B3c4c(cc5ccccc5c4N(c4ccc(C(C)(C)C)cc4-c4ccccc4)c4ccc5oc6ccccc6c5c43)-c3ccc(-c4ccccc4)cc32)cc1] 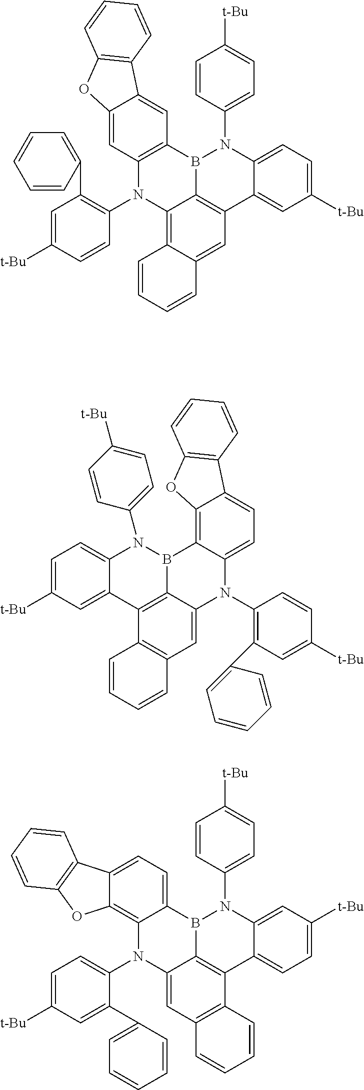 [SMILES: CC(C)(C)c1ccc(N2B3c4cc5c(cc4N(c4ccc(C(C)(C)C)cc4-c4ccccc4)c4c3c(cc3ccccc43)-c3cc(C(C)(C)C)ccc32)oc2ccccc25)cc1 ; CC(C)(C)c1ccc(N2B3c4c(cc5ccccc5c4-c4cc(C(C)(C)C)ccc42)N(c2ccc(C(C)(C)C)cc2-c2ccccc2)c2ccc4c(oc5ccccc54)c23)cc1 ; CC(C)(C)c1ccc(N2B3c4ccc5c(oc6ccccc65)c4N(c4ccc(C(C)(C)C)cc4-c4ccccc4)c4cc5ccccc5c(c43)-c3ccc(C(C)(C)C)cc32)cc1] 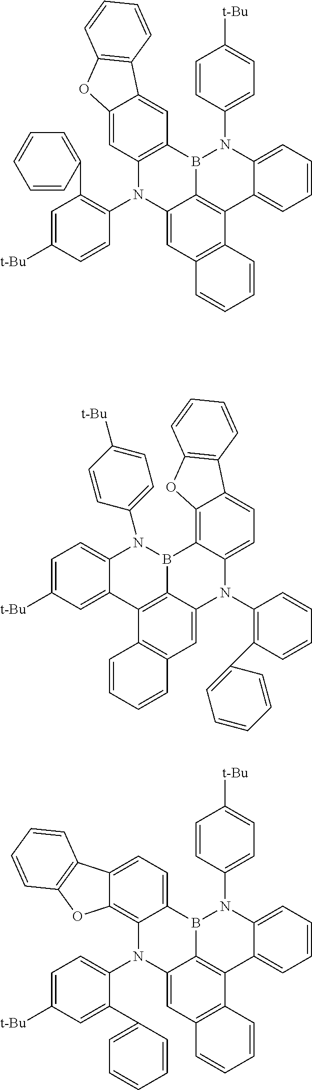 [SMILES: CC(C)(C)c1ccc(N2B3c4cc5c(cc4N(c4ccc(C(C)(C)C)cc4-c4ccccc4)c4cc6ccccc6c(c43)-c3ccccc32)oc2ccccc25)cc1 ; CC(C)(C)c1ccc(N2B3c4c(cc5ccccc5c4-c4cc(C(C)(C)C)ccc42)N(c2ccccc2-c2ccccc2)c2ccc4c(oc5ccccc54)c23)cc1 ; CC(C)(C)c1ccc(N2B3c4ccc5c(oc6ccccc65)c4N(c4ccc(C(C)(C)C)cc4-c4ccccc4)c4cc5ccccc5c(c43)-c3ccccc32)cc1] 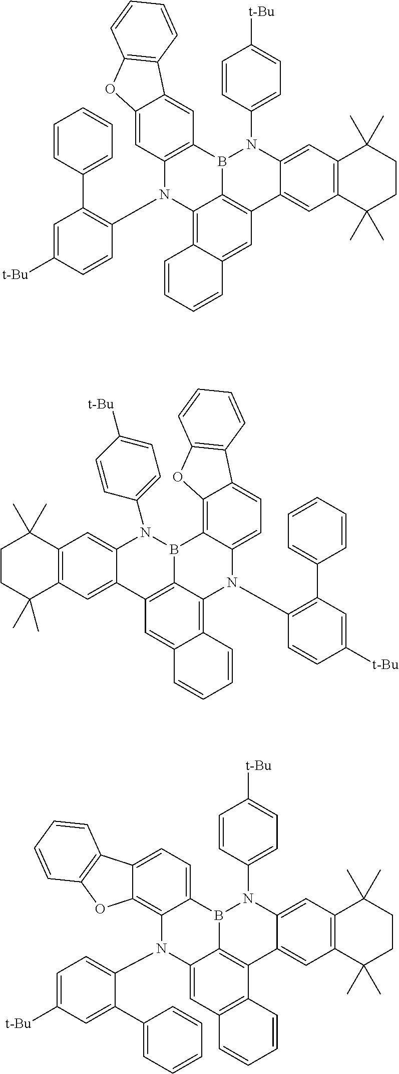 [SMILES: CC(C)(C)c1ccc(N2B3c4cc5c(cc4N(c4ccc(C(C)(C)C)cc4-c4ccccc4)c4c3c(cc3ccccc43)-c3cc4c(cc32)C(C)(C)CCC4(C)C)oc2ccccc25)cc1 ; CC(C)(C)c1ccc(N2B3c4c(cc5ccccc5c4N(c4ccc(C(C)(C)C)cc4-c4ccccc4)c4ccc5c(oc6ccccc65)c43)-c3cc4c(cc32)C(C)(C)CCC4(C)C)cc1 ; CC(C)(C)c1ccc(N2B3c4ccc5c(oc6ccccc65)c4N(c4ccc(C(C)(C)C)cc4-c4ccccc4)c4cc5ccccc5c(c43)-c3cc4c(cc32)C(C)(C)CCC4(C)C)cc1] 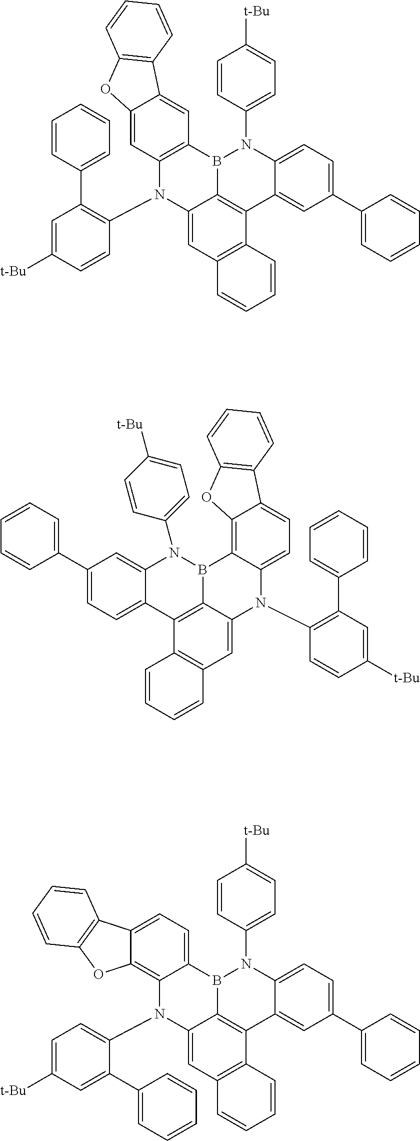 [SMILES: CC(C)(C)c1ccc(N2B3c4cc5c(cc4N(c4ccc(C(C)(C)C)cc4-c4ccccc4)c4cc6ccccc6c(c43)-c3cc(-c4ccccc4)ccc32)oc2ccccc25)cc1 ; CC(C)(C)c1ccc(N2B3c4c(cc5ccccc5c4-c4ccc(-c5ccccc5)cc42)N(c2ccc(C(C)(C)C)cc2-c2ccccc2)c2ccc4c(oc5ccccc54)c23)cc1 ; CC(C)(C)c1ccc(N2B3c4ccc5c(oc6ccccc65)c4N(c4ccc(C(C)(C)C)cc4-c4ccccc4)c4cc5ccccc5c(c43)-c3cc(-c4ccccc4)ccc32)cc1] 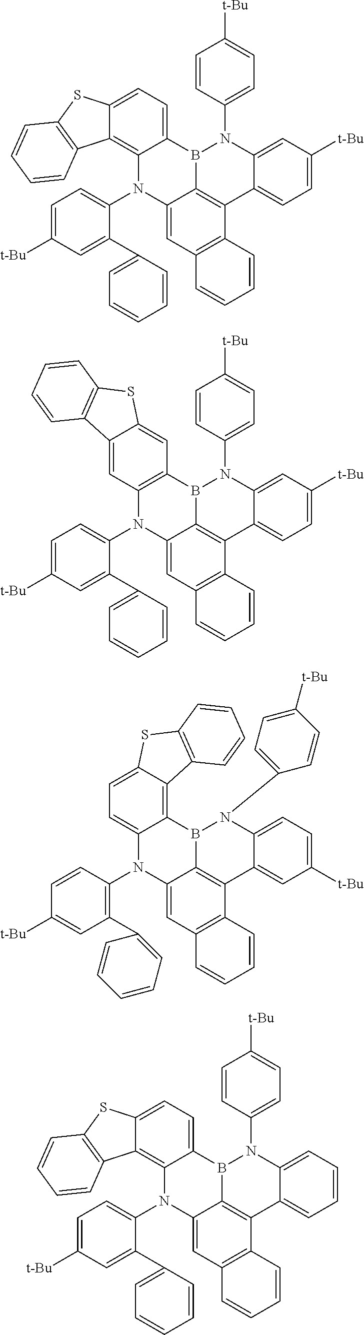 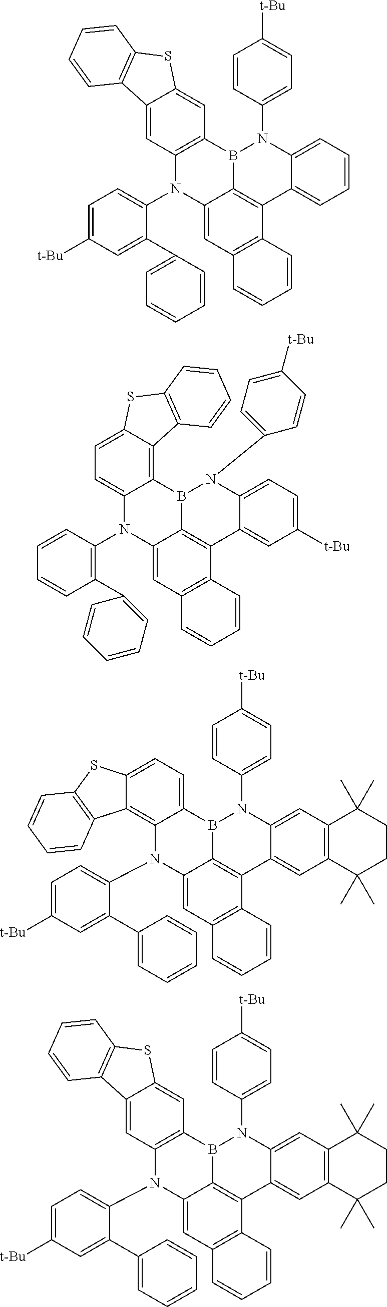 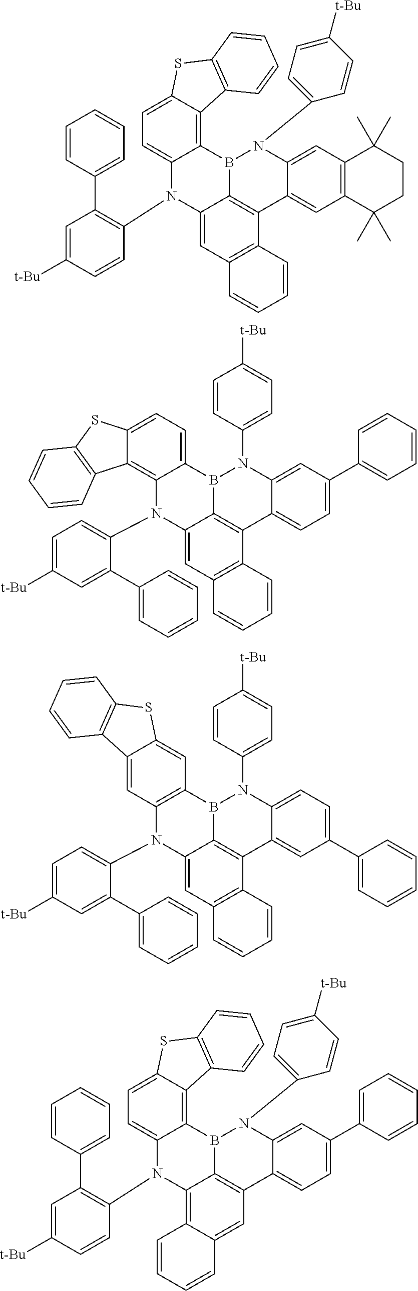 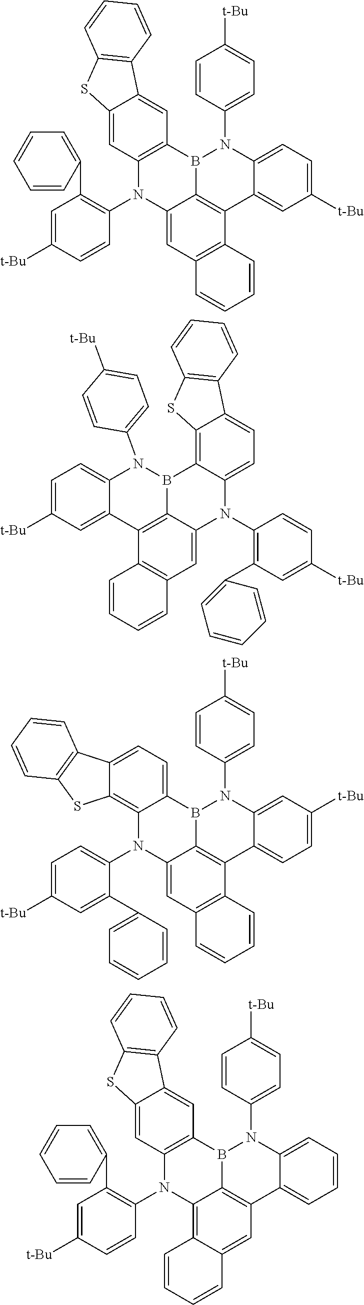 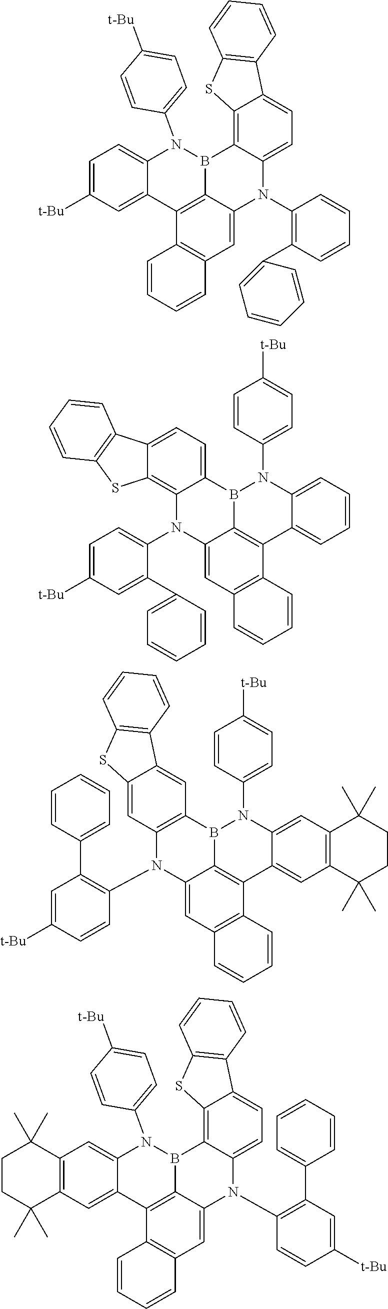 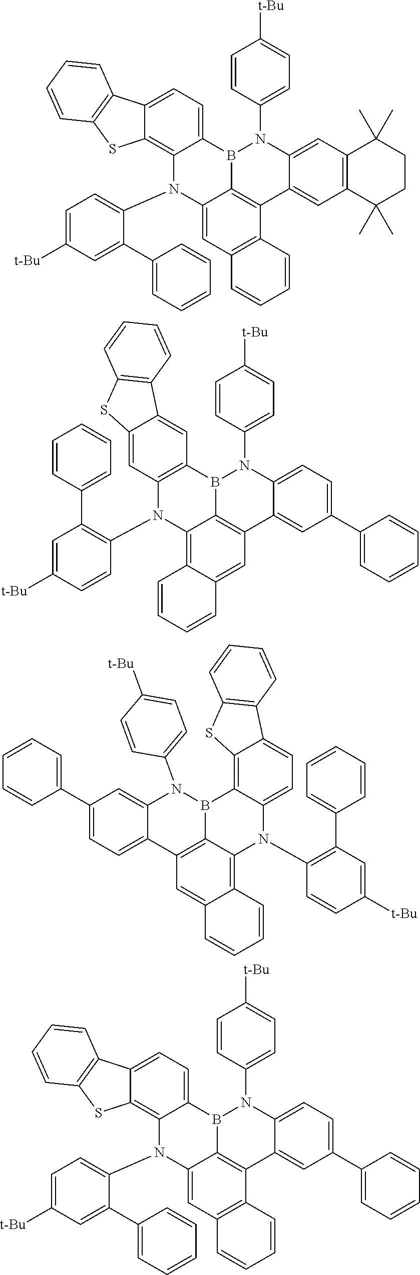 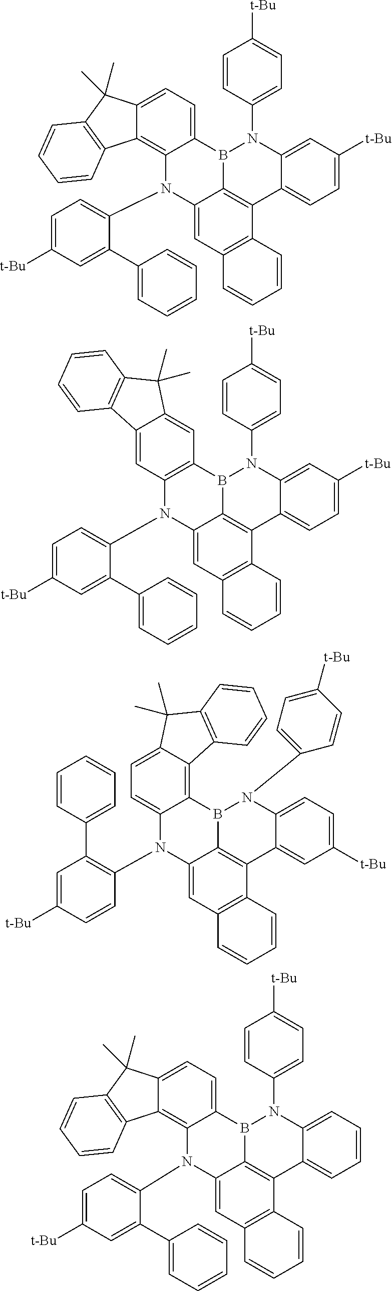 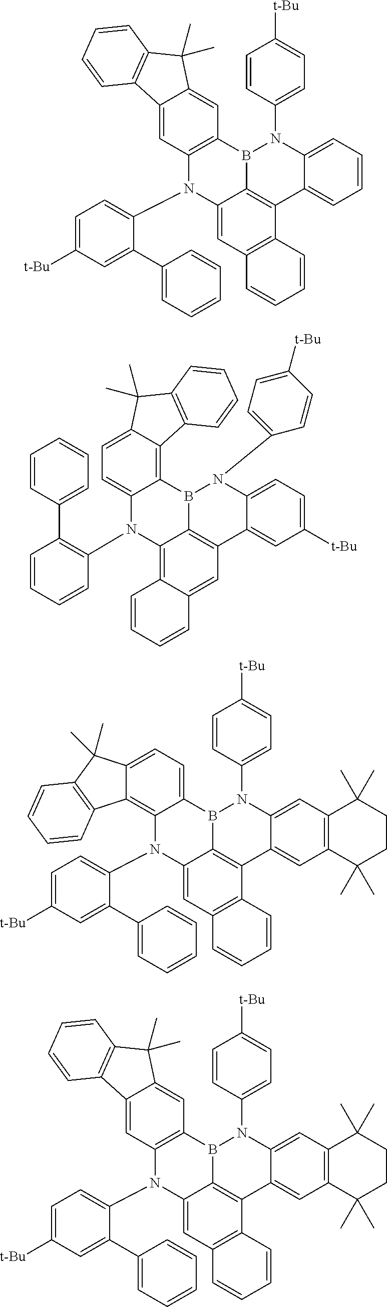 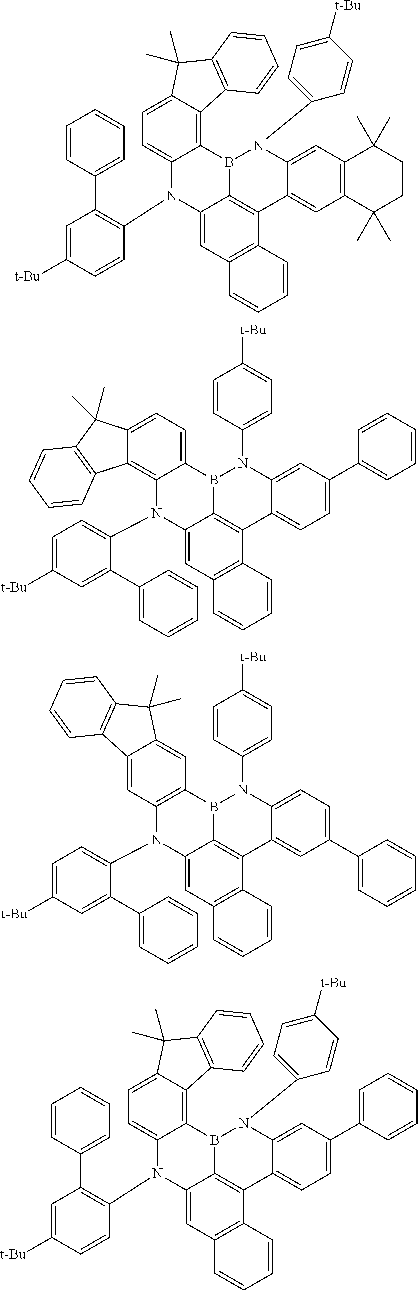 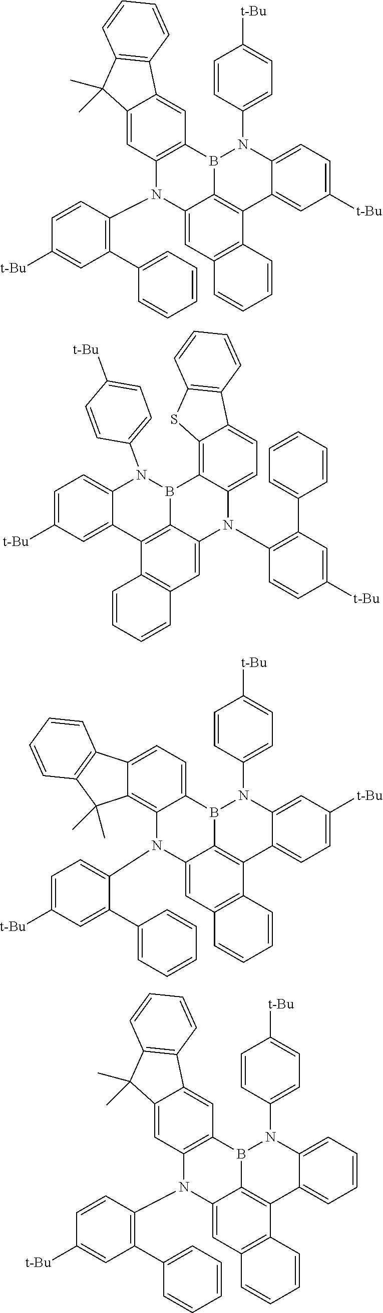 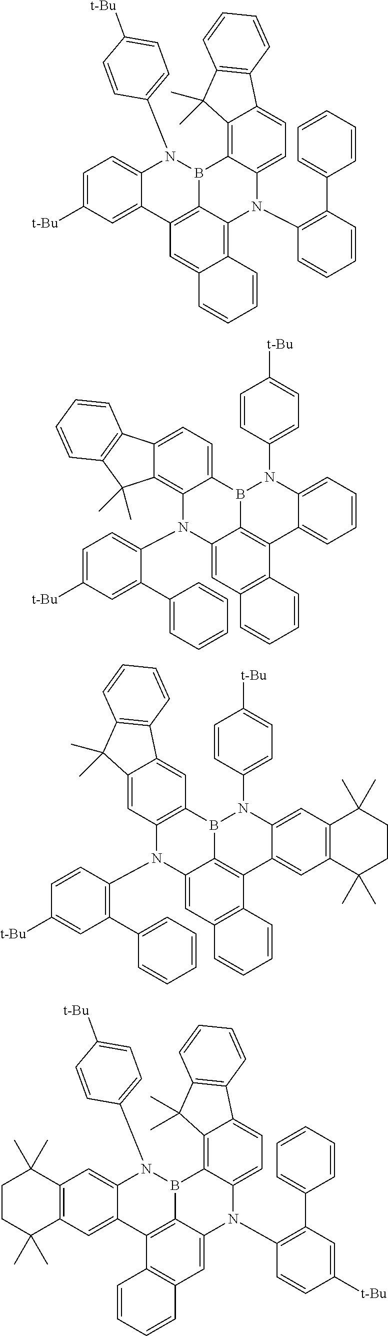 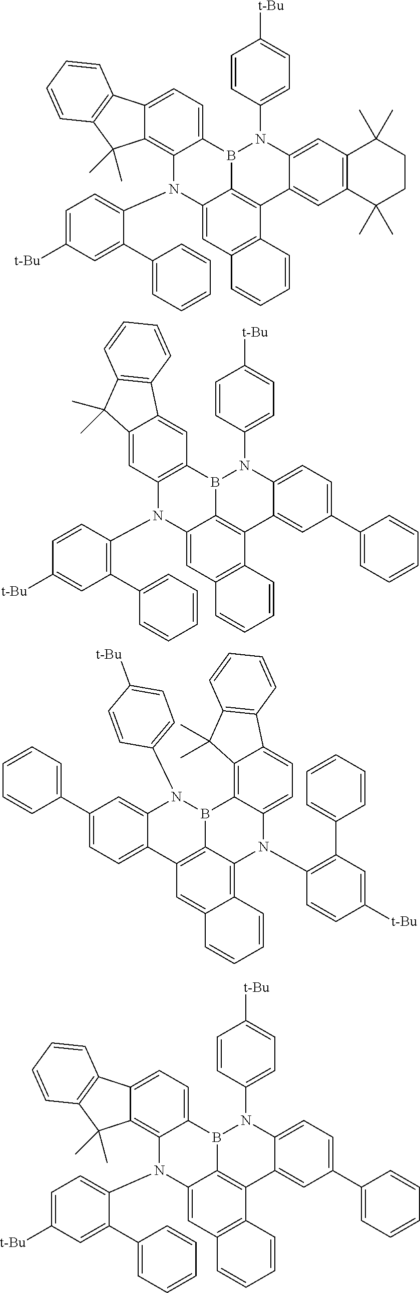 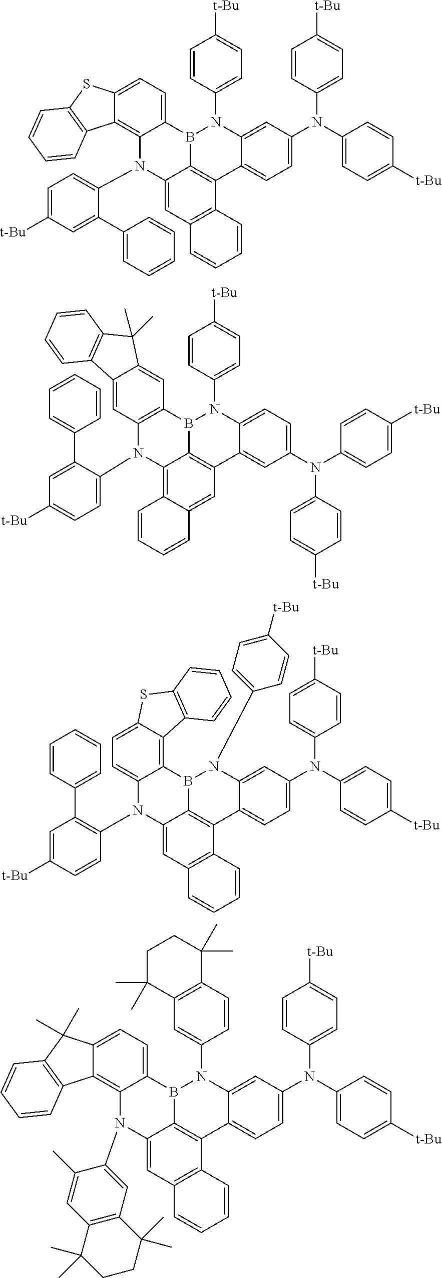 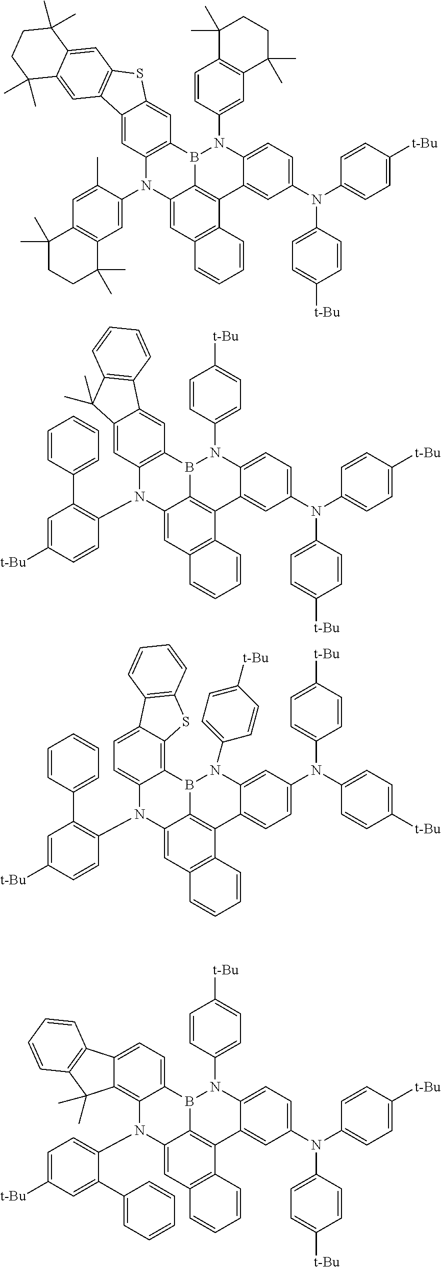 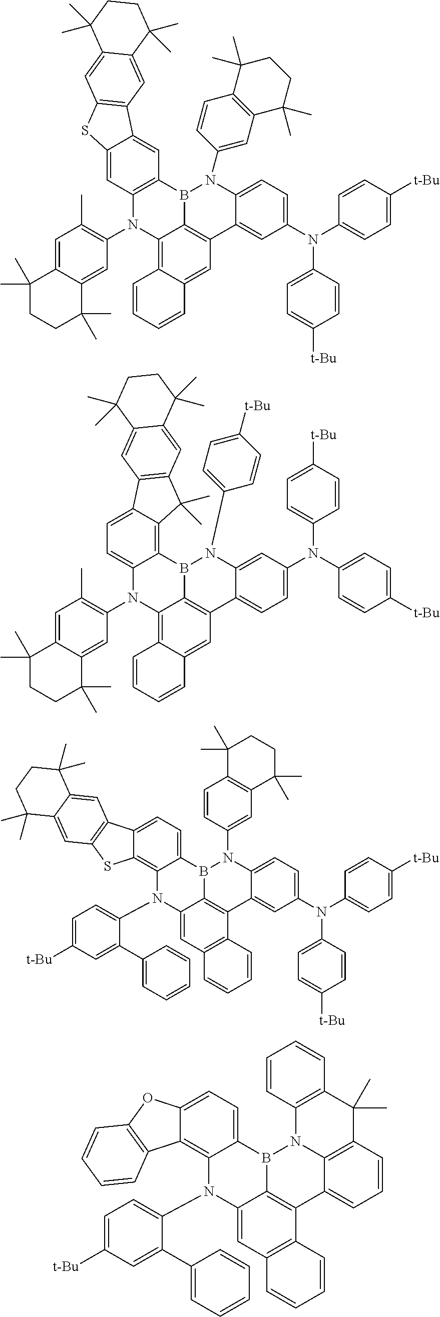 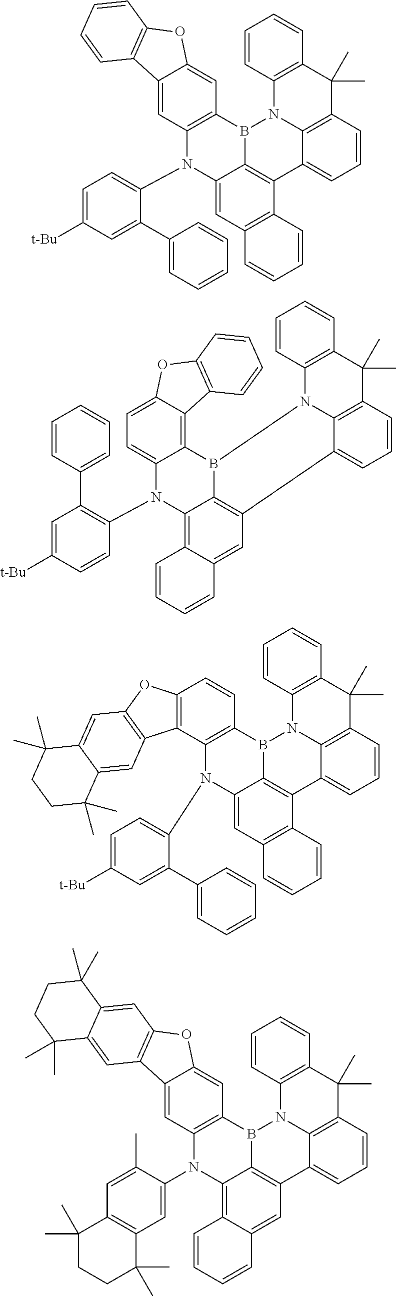 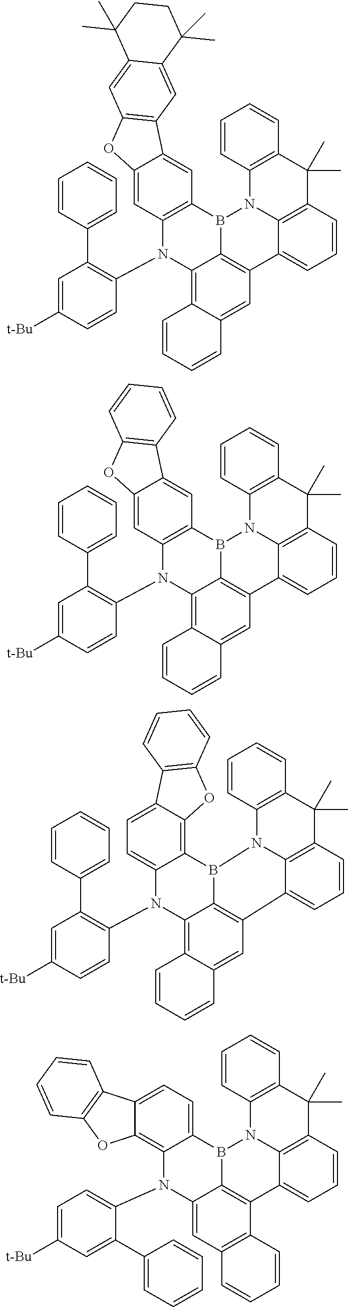 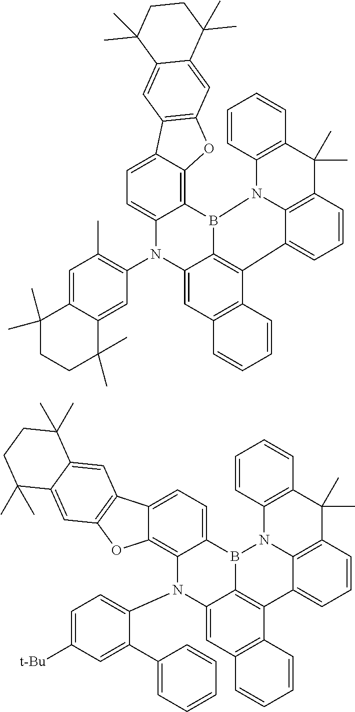 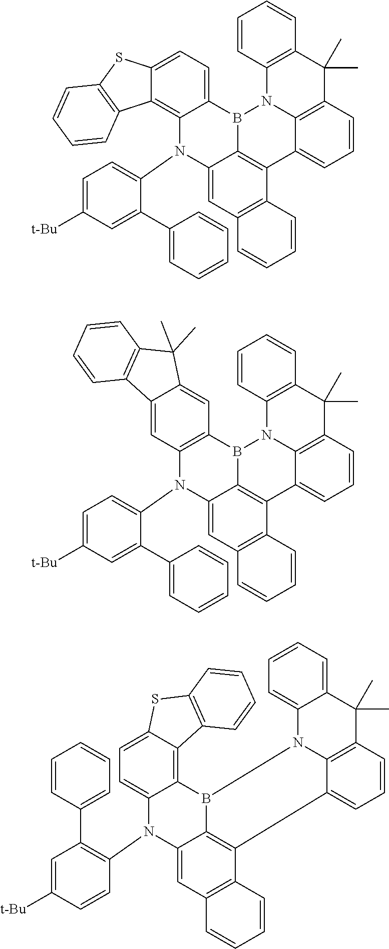 [SMILES: CC(C)(C)c1ccc(N2c3cc4ccccc4c4c3B(c3ccc5sc6ccccc6c5c32)N2c3ccccc3C(C)(C)c3cccc-4c32)c(-c2ccccc2)c1 ; CC(C)(C)c1ccc(N2c3cc4c(cc3B3c5c2cc2ccccc2c5-c2cccc5c2N3c2ccccc2C5(C)C)C(C)(C)c2ccccc2-4)c(-c2ccccc2)c1 ; CC(C)(C)c1ccc(N2c3cc4ccccc4c4c3B(c3c2ccc2sc5ccccc5c32)N2c3ccccc3C(C)(C)c3cccc-4c32)c(-c2ccccc2)c1] 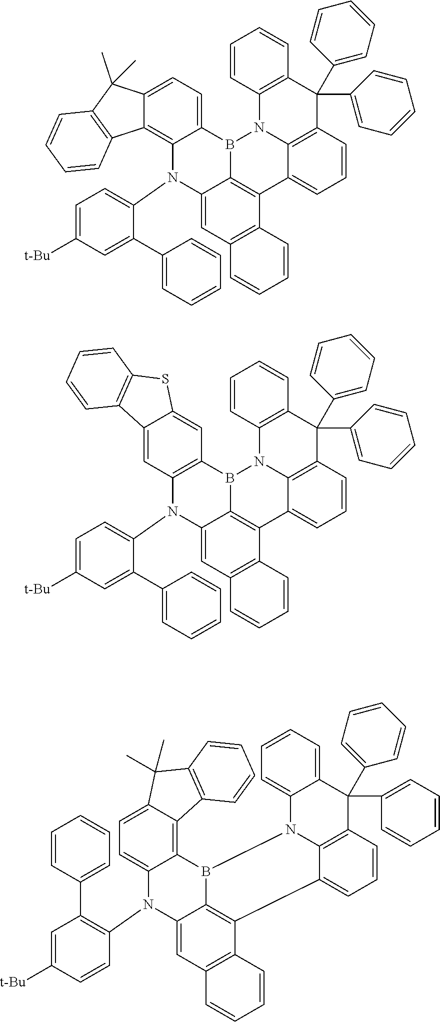 [SMILES: CC(C)(C)c1ccc(N2c3cc4ccccc4c4c3B(c3ccc5c(c32)-c2ccccc2C5(C)C)N2c3ccccc3C(c3ccccc3)(c3ccccc3)c3cccc-4c32)c(-c2ccccc2)c1 ; CC(C)(C)c1ccc(N2c3cc4c(cc3B3c5c2cc2ccccc2c5-c2cccc5c2N3c2ccccc2C5(c2ccccc2)c2ccccc2)sc2ccccc24)c(-c2ccccc2)c1 ; CC(C)(C)c1ccc(N2c3ccc4c(c3B3c5c2cc2ccccc2c5-c2cccc5c2N3c2ccccc2C5(c2ccccc2)c2ccccc2)-c2ccccc2C4(C)C)c(-c2ccccc2)c1] 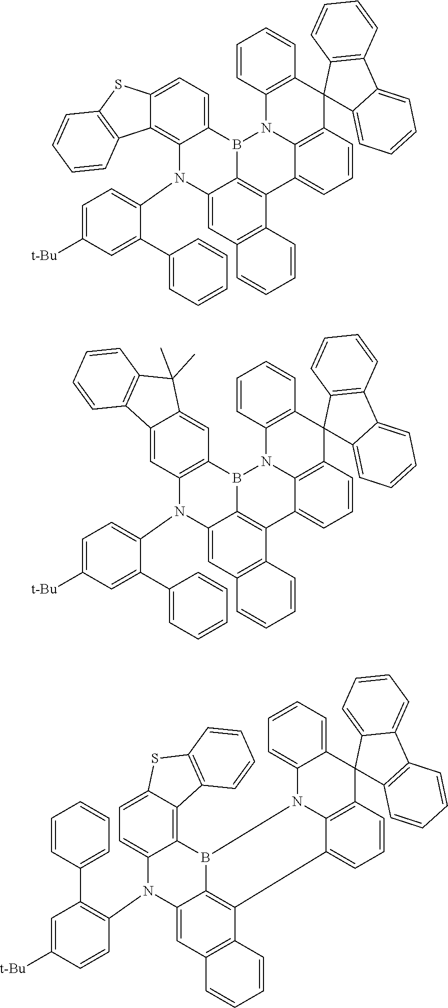 [SMILES: CC(C)(C)c1ccc(N2c3cc4ccccc4c4c3B(c3ccc5sc6ccccc6c5c32)N2c3ccccc3C3(c5ccccc5-c5ccccc53)c3cccc-4c32)c(-c2ccccc2)c1 ; CC(C)(C)c1ccc(N2c3cc4c(cc3B3c5c2cc2ccccc2c5-c2cccc5c2N3c2ccccc2C52c3ccccc3-c3ccccc32)C(C)(C)c2ccccc2-4)c(-c2ccccc2)c1 ; CC(C)(C)c1ccc(N2c3cc4ccccc4c4c3B(c3c2ccc2sc5ccccc5c32)N2c3ccccc3C3(c5ccccc5-c5ccccc53)c3cccc-4c32)c(-c2ccccc2)c1] 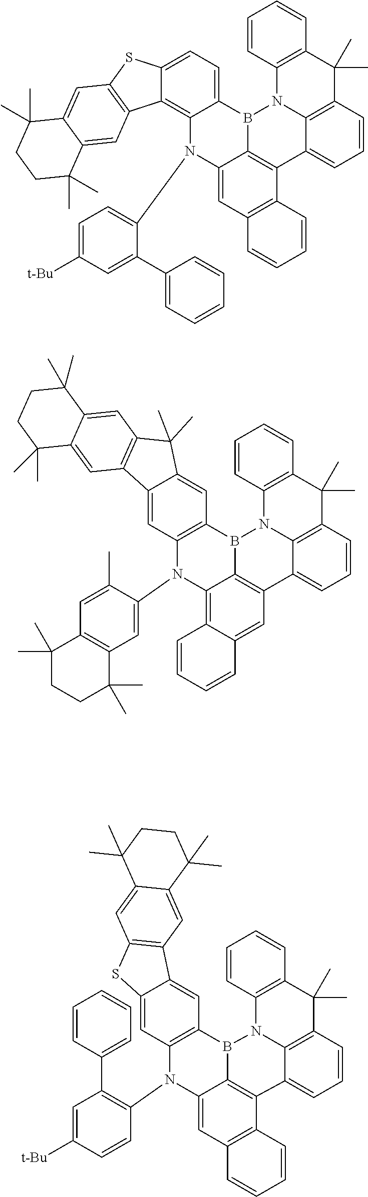 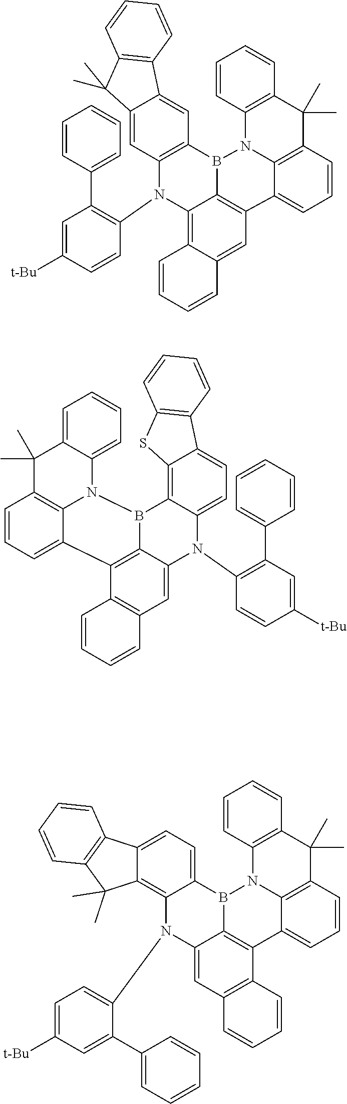 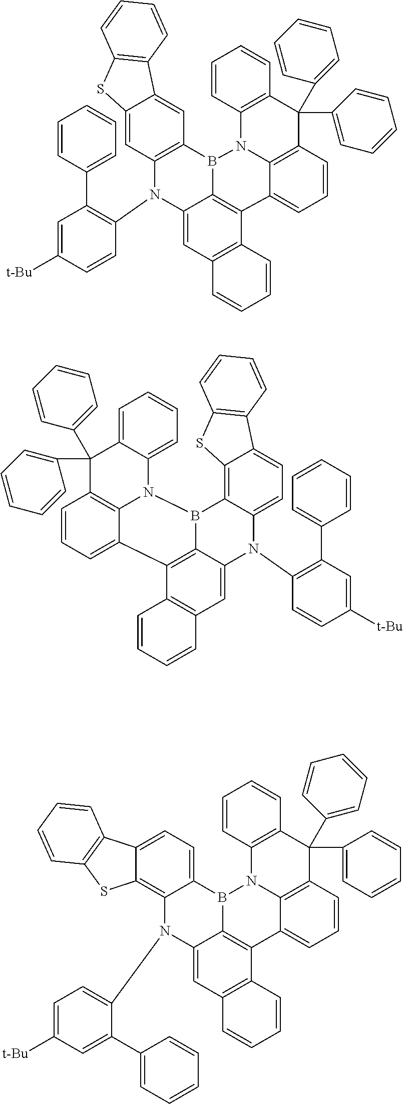 [SMILES: CC(C)(C)c1ccc(N2c3cc4sc5ccccc5c4cc3B3c4c2cc2ccccc2c4-c2cccc4c2N3c2ccccc2C4(c2ccccc2)c2ccccc2)c(-c2ccccc2)c1 ; CC(C)(C)c1ccc(N2c3cc4ccccc4c4c3B(c3c2ccc2c3sc3ccccc32)N2c3ccccc3C(c3ccccc3)(c3ccccc3)c3cccc-4c32)c(-c2ccccc2)c1 ; CC(C)(C)c1ccc(N2c3cc4ccccc4c4c3B(c3ccc5c(sc6ccccc65)c32)N2c3ccccc3C(c3ccccc3)(c3ccccc3)c3cccc-4c32)c(-c2ccccc2)c1] 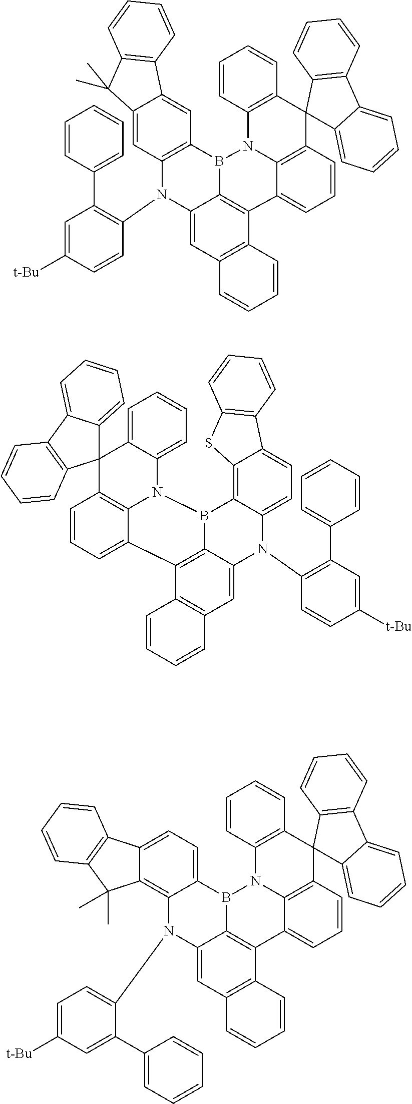 [SMILES: CC(C)(C)c1ccc(N2c3cc4c(cc3B3c5c2cc2ccccc2c5-c2cccc5c2N3c2ccccc2C52c3ccccc3-c3ccccc32)-c2ccccc2C4(C)C)c(-c2ccccc2)c1 ; CC(C)(C)c1ccc(N2c3cc4ccccc4c4c3B(c3c2ccc2c3sc3ccccc32)N2c3ccccc3C3(c5ccccc5-c5ccccc53)c3cccc-4c32)c(-c2ccccc2)c1 ; CC(C)(C)c1ccc(N2c3cc4ccccc4c4c3B(c3ccc5c(c32)C(C)(C)c2ccccc2-5)N2c3ccccc3C3(c5ccccc5-c5ccccc53)c3cccc-4c32)c(-c2ccccc2)c1] 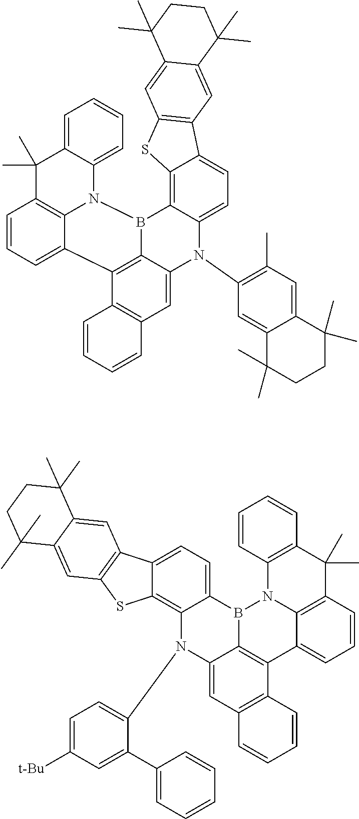 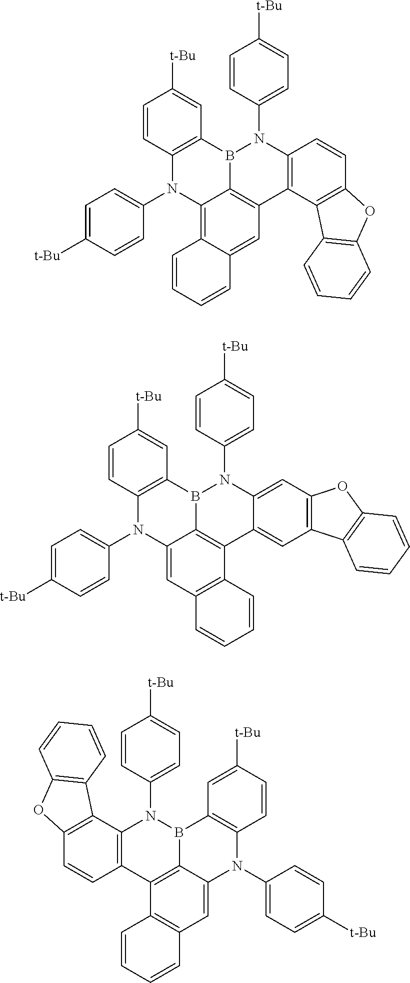 [SMILES: CC(C)(C)c1ccc(N2B3c4cc(C(C)(C)C)ccc4N(c4ccc(C(C)(C)C)cc4)c4c3c(cc3ccccc43)-c3c2ccc2oc4ccccc4c32)cc1 ; CC(C)(C)c1ccc(N2B3c4cc(C(C)(C)C)ccc4N(c4ccc(C(C)(C)C)cc4)c4cc5ccccc5c(c43)-c3cc4c(cc32)oc2ccccc24)cc1 ; CC(C)(C)c1ccc(N2B3c4cc(C(C)(C)C)ccc4N(c4ccc(C(C)(C)C)cc4)c4cc5ccccc5c(c43)-c3ccc4oc5ccccc5c4c32)cc1] 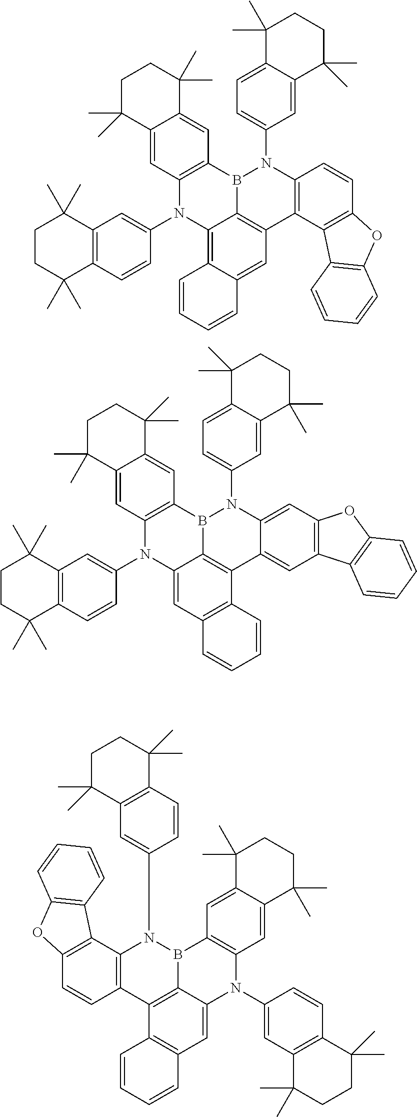 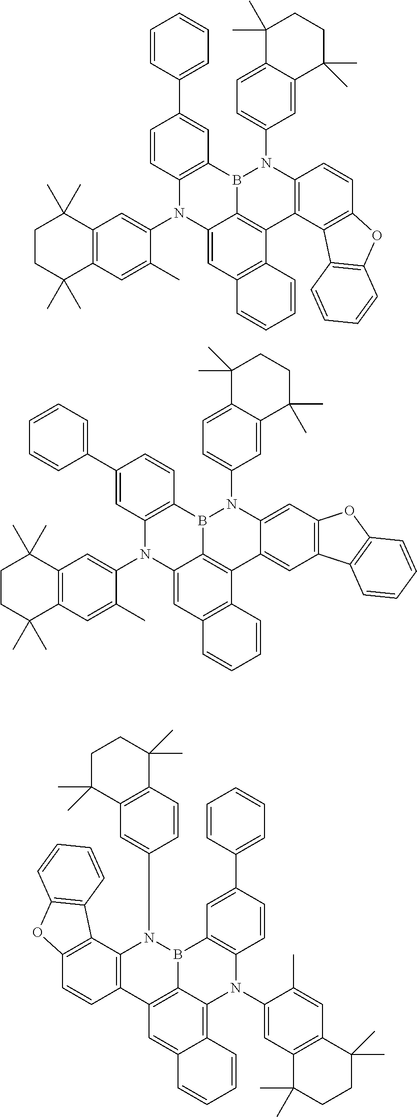 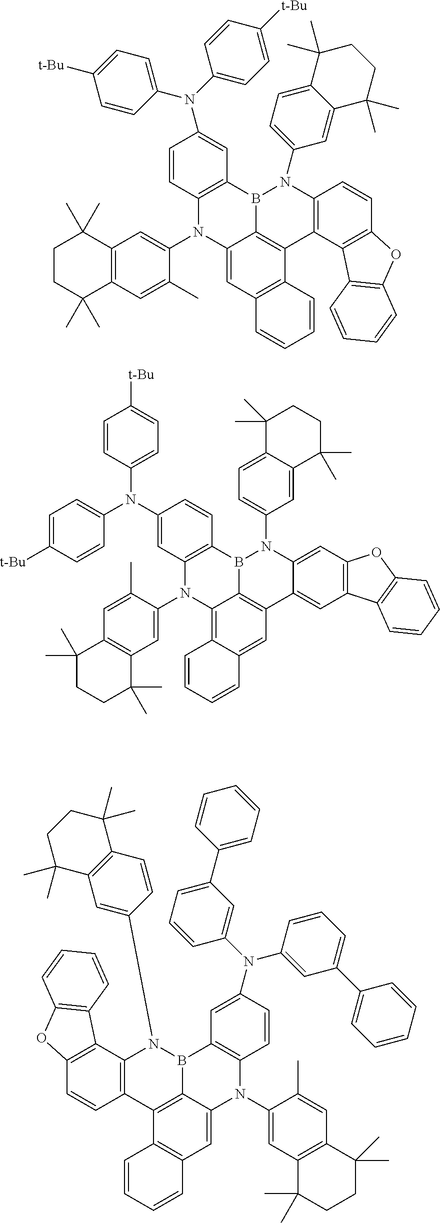 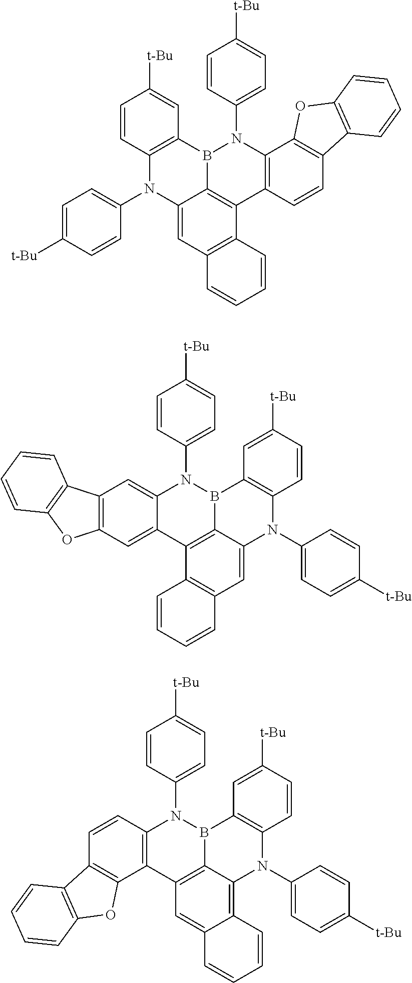 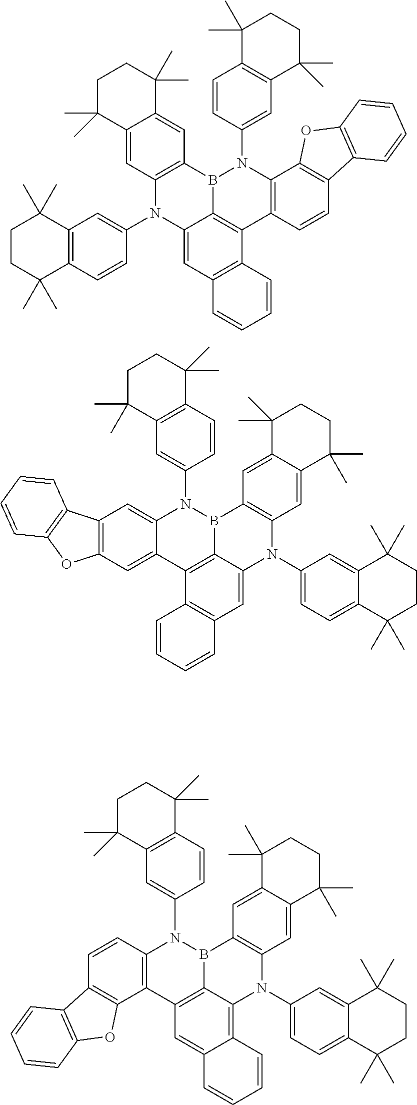 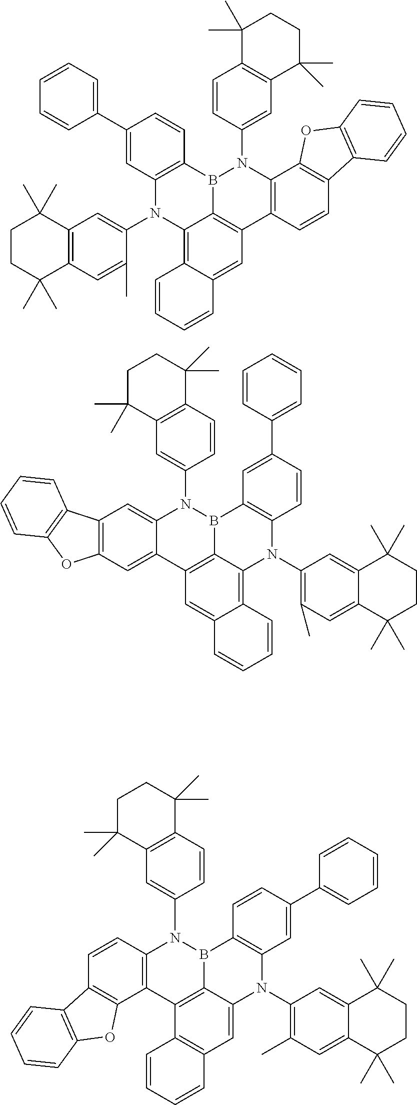 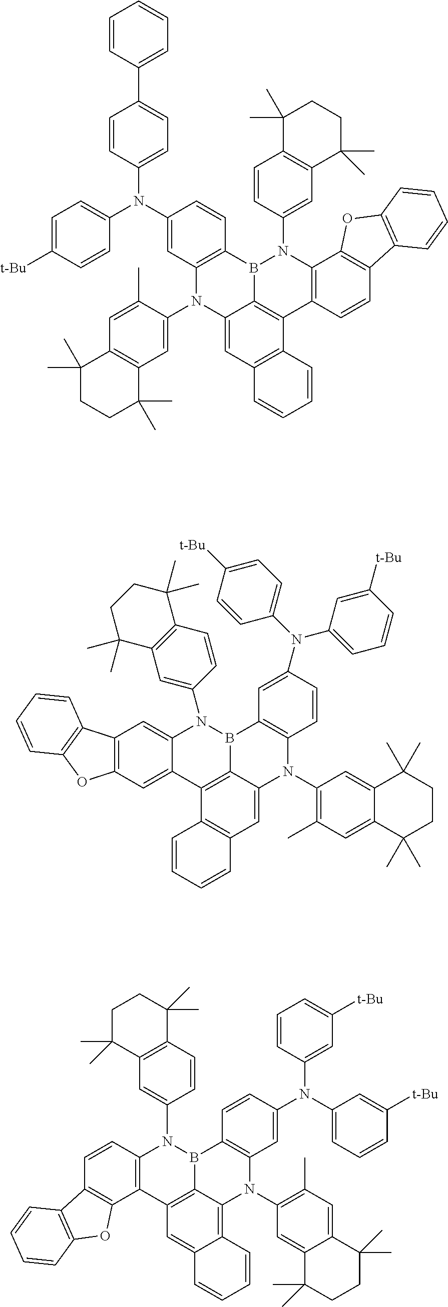 [SMILES: Cc1cc2c(cc1N1c3cc(N(c4ccc(-c5ccccc5)cc4)c4ccc(C(C)(C)C)cc4)ccc3B3c4c1cc1ccccc1c4-c1ccc4c(oc5ccccc54)c1N3c1ccc3c(c1)C(C)(C)CCC3(C)C)C(C)(C)CCC2(C)C ; Cc1cc2c(cc1N1c3ccc(N(c4ccc(C(C)(C)C)cc4)c4cccc(C(C)(C)C)c4)cc3B3c4c1cc1ccccc1c4-c1cc4oc5ccccc5c4cc1N3c1ccc3c(c1)C(C)(C)CCC3(C)C)C(C)(C)CCC2(C)C ; Cc1cc2c(cc1N1c3cc(N(c4cccc(C(C)(C)C)c4)c4cccc(C(C)(C)C)c4)ccc3B3c4c(cc5ccccc5c41)-c1c(ccc4c1oc1ccccc14)N3c1ccc3c(c1)C(C)(C)CCC3(C)C)C(C)(C)CCC2(C)C] 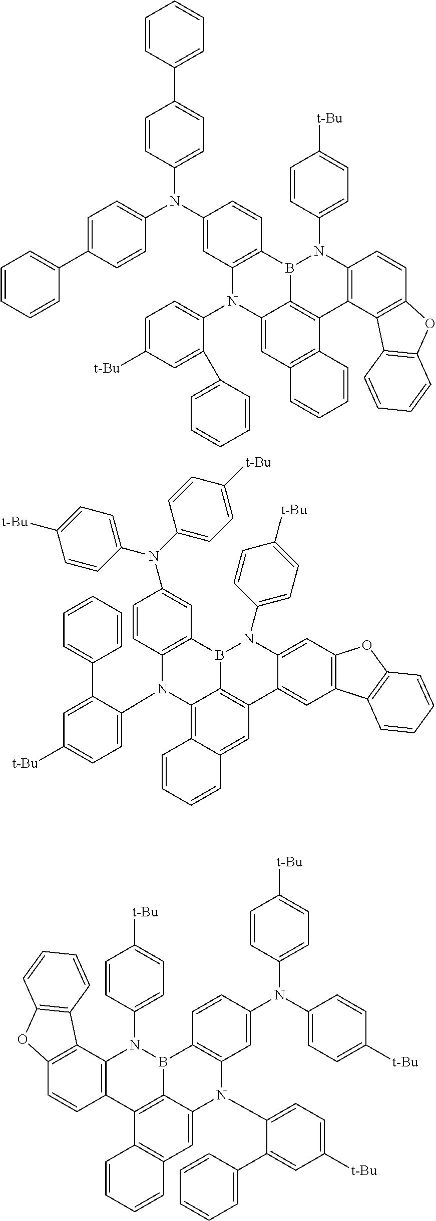 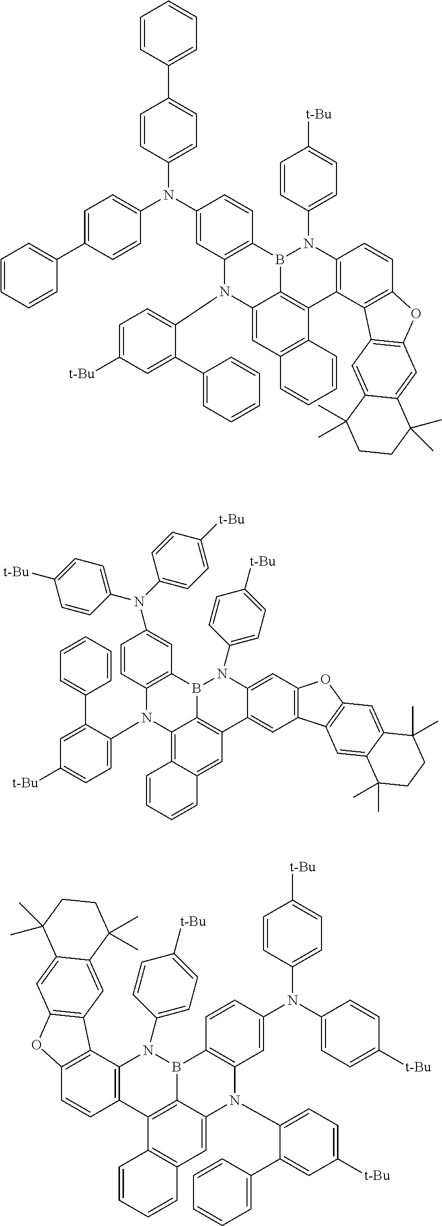 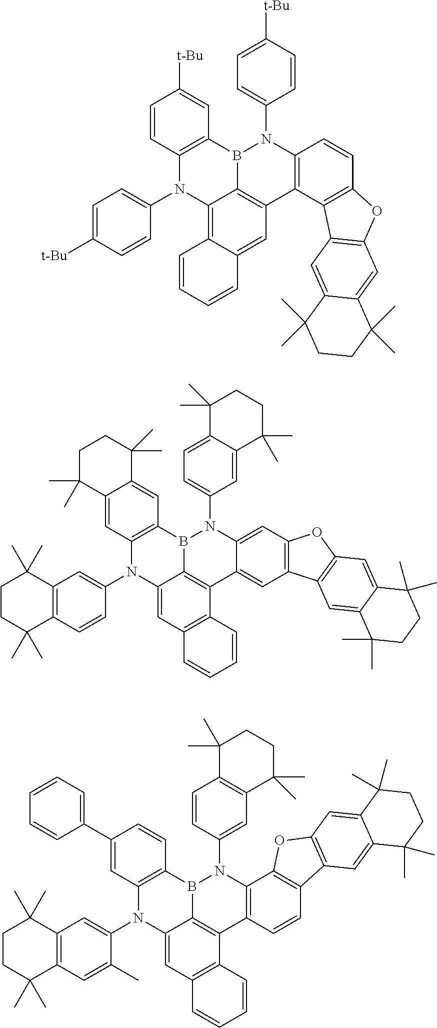 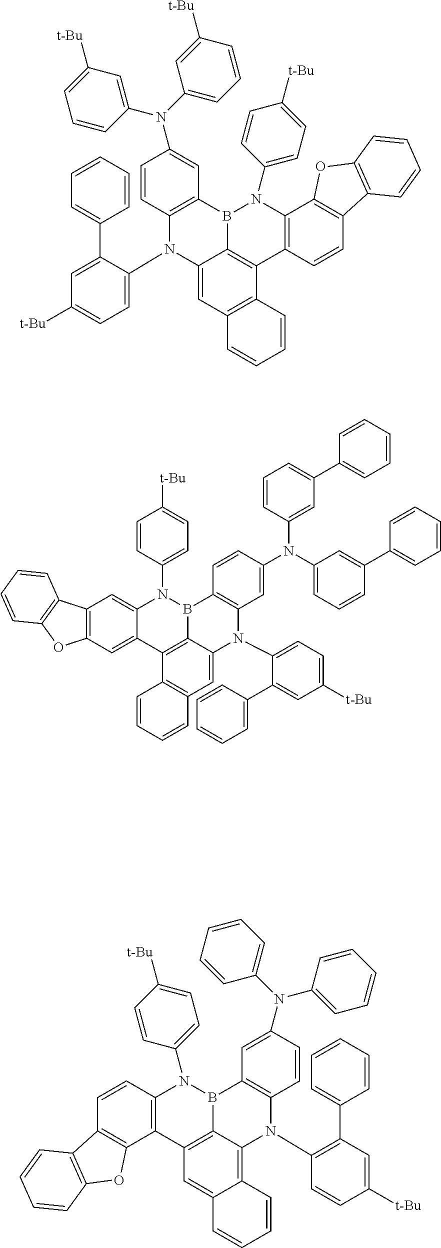 [SMILES: CC(C)(C)c1ccc(N2B3c4cc(N(c5cccc(C(C)(C)C)c5)c5cccc(C(C)(C)C)c5)ccc4N(c4ccc(C(C)(C)C)cc4-c4ccccc4)c4cc5ccccc5c(c43)-c3ccc4c(oc5ccccc54)c32)cc1 ; CC(C)(C)c1ccc(N2B3c4ccc(N(c5cccc(-c6ccccc6)c5)c5cccc(-c6ccccc6)c5)cc4N(c4ccc(C(C)(C)C)cc4-c4ccccc4)c4cc5ccccc5c(c43)-c3cc4oc5ccccc5c4cc32)cc1 ; CC(C)(C)c1ccc(N2B3c4cc(N(c5ccccc5)c5ccccc5)ccc4N(c4ccc(C(C)(C)C)cc4-c4ccccc4)c4c3c(cc3ccccc43)-c3c2ccc2c3oc3ccccc32)cc1] 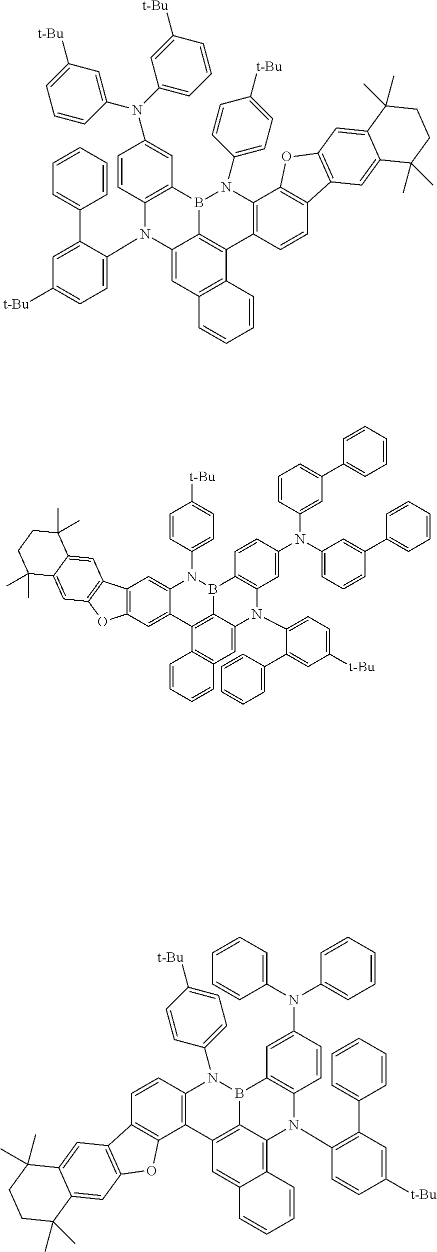 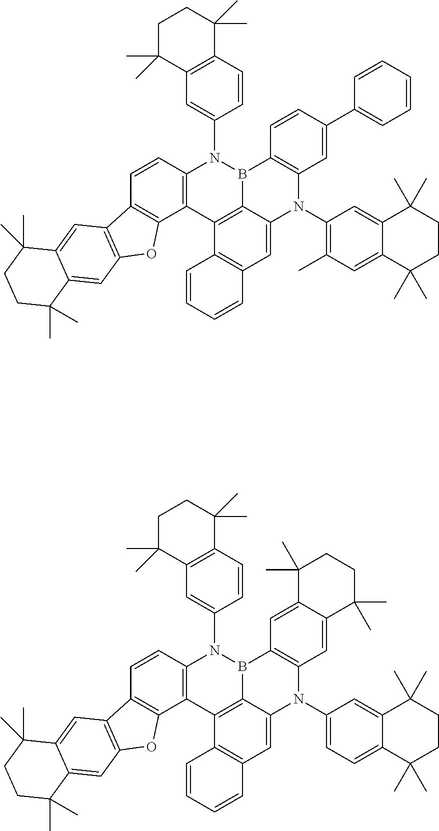 [SMILES: Cc1cc2c(cc1N1c3cc(-c4ccccc4)ccc3B3c4c1cc1ccccc1c4-c1c(ccc4c1oc1cc5c(cc14)C(C)(C)CCC5(C)C)N3c1ccc3c(c1)C(C)(C)CCC3(C)C)C(C)(C)CCC2(C)C ; CC1(C)CCC(C)(C)c2cc(N3B4c5cc6c(cc5N(c5ccc7c(c5)C(C)(C)CCC7(C)C)c5cc7ccccc7c(c54)-c4c3ccc3c4oc4cc5c(cc43)C(C)(C)CCC5(C)C)C(C)(C)CCC6(C)C)ccc21] 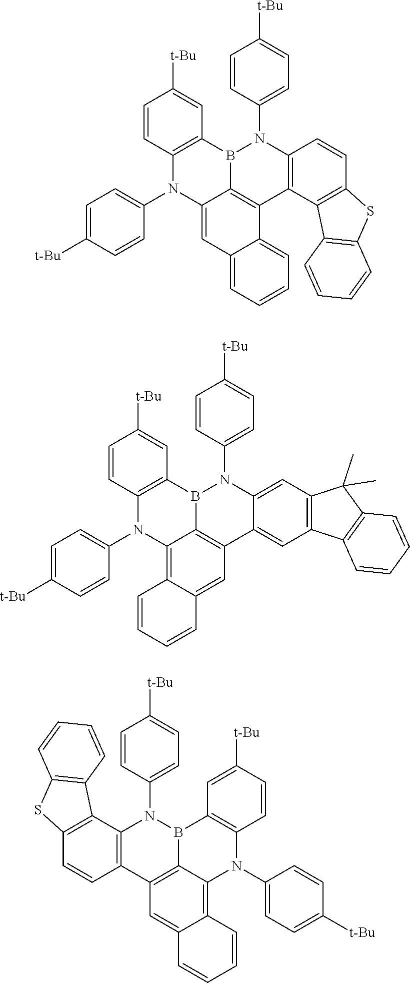 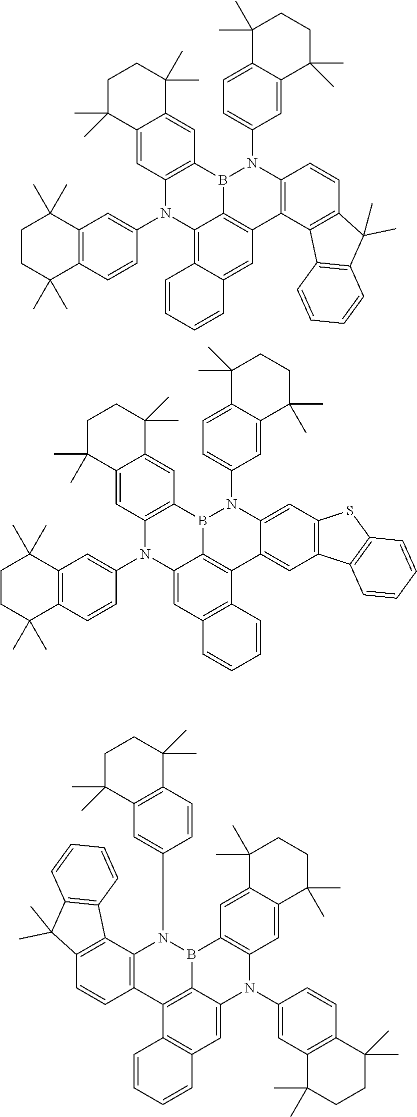 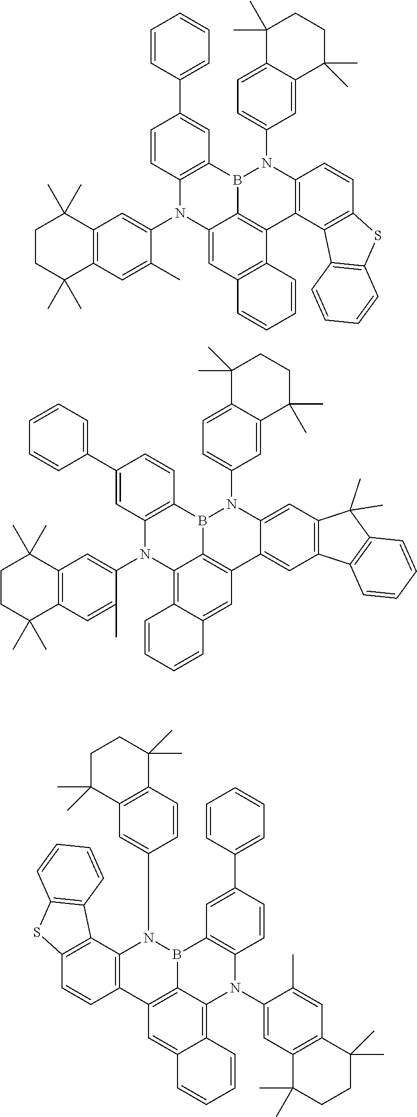 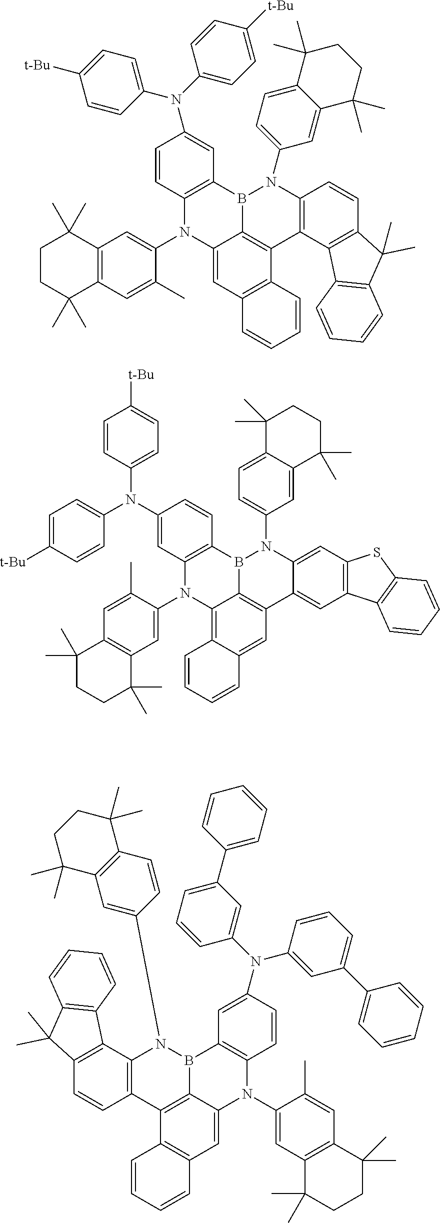 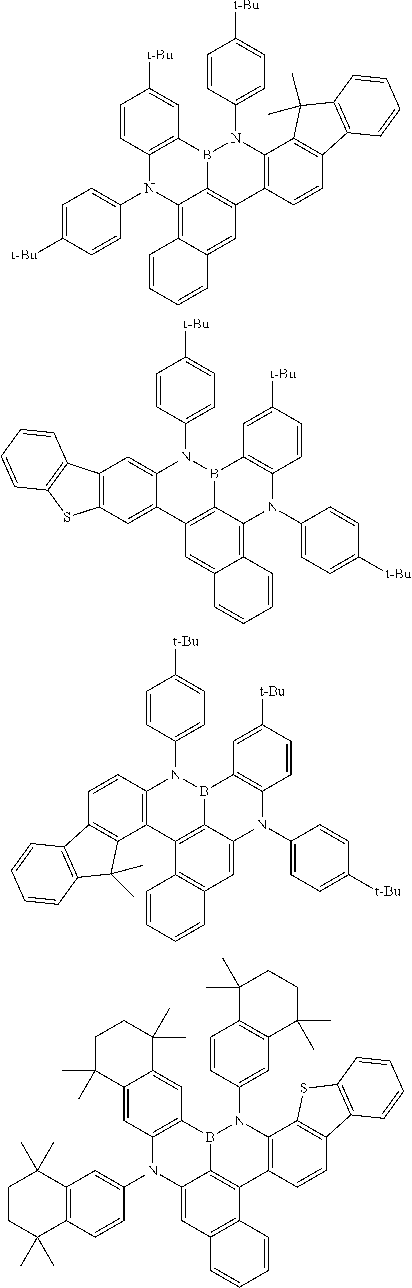 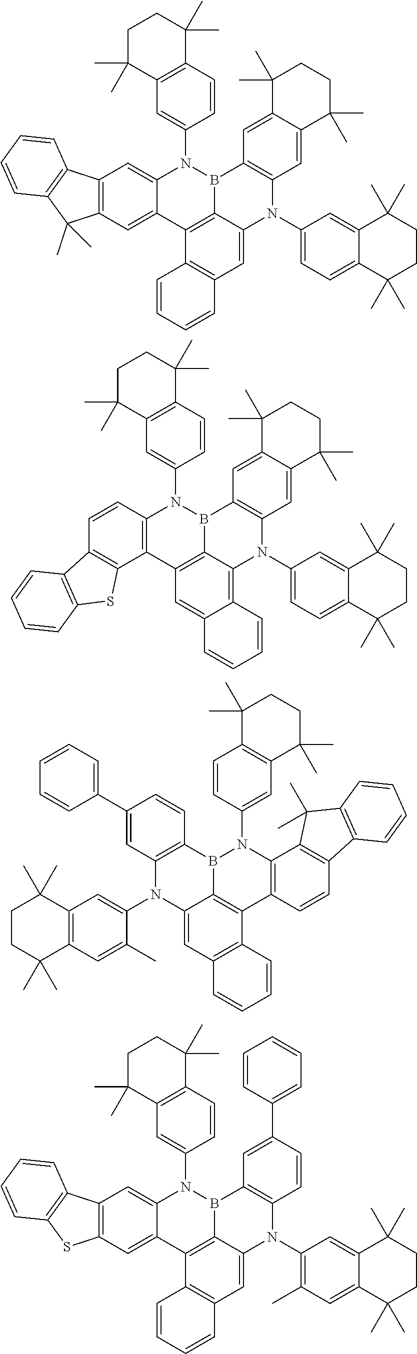 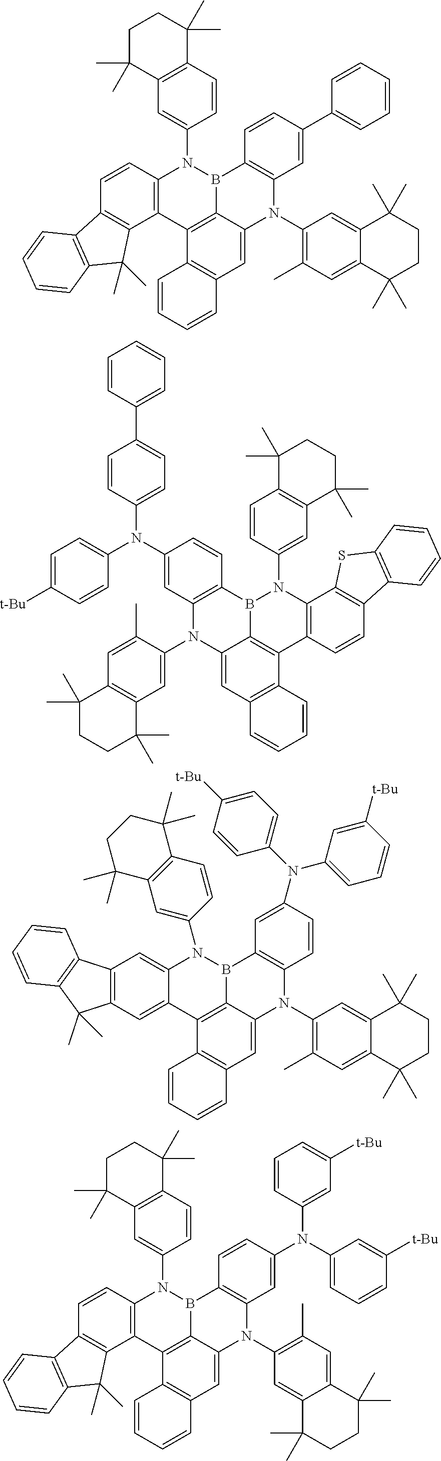 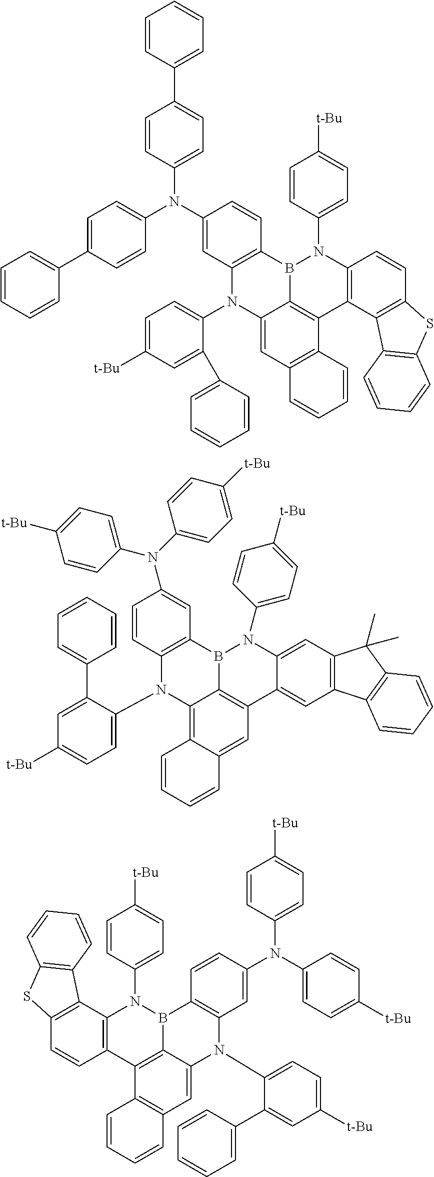 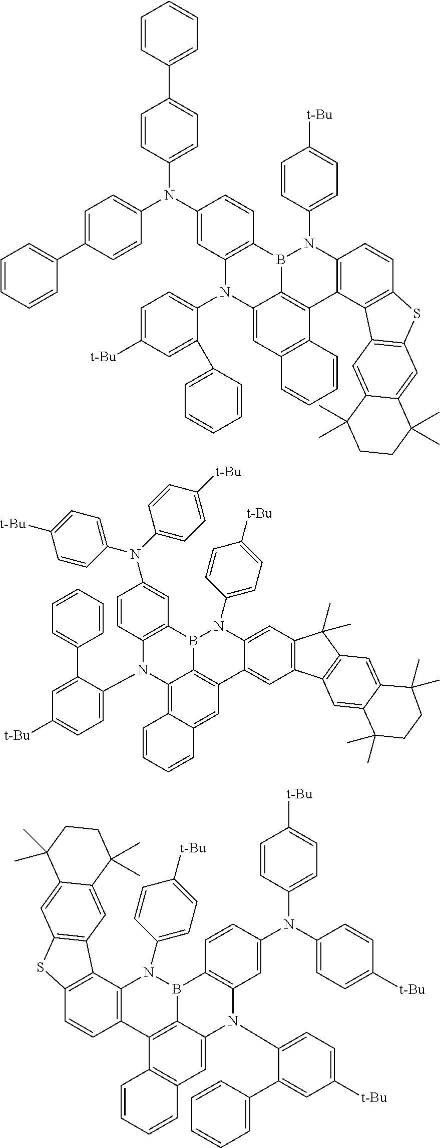 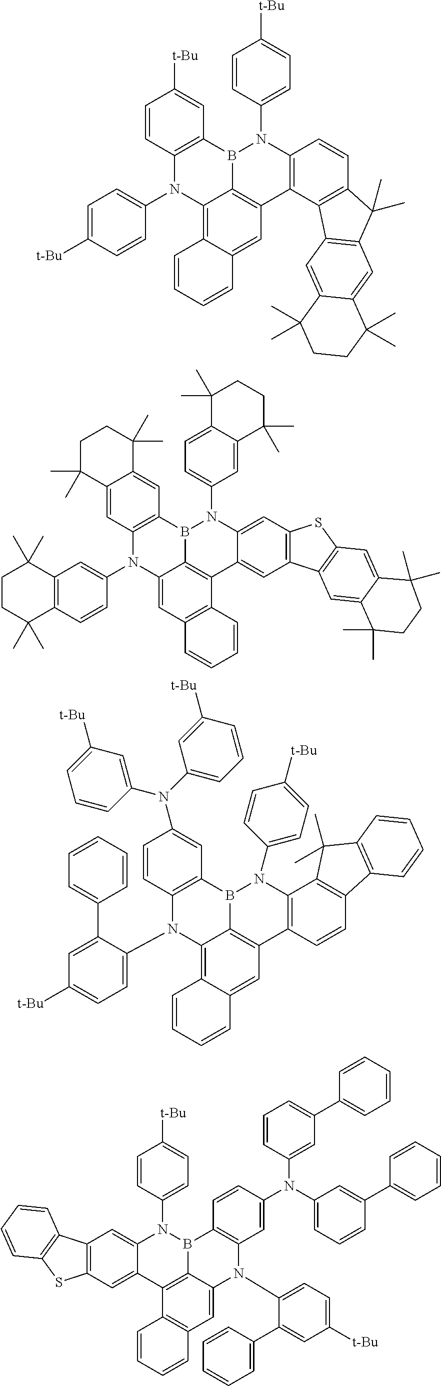 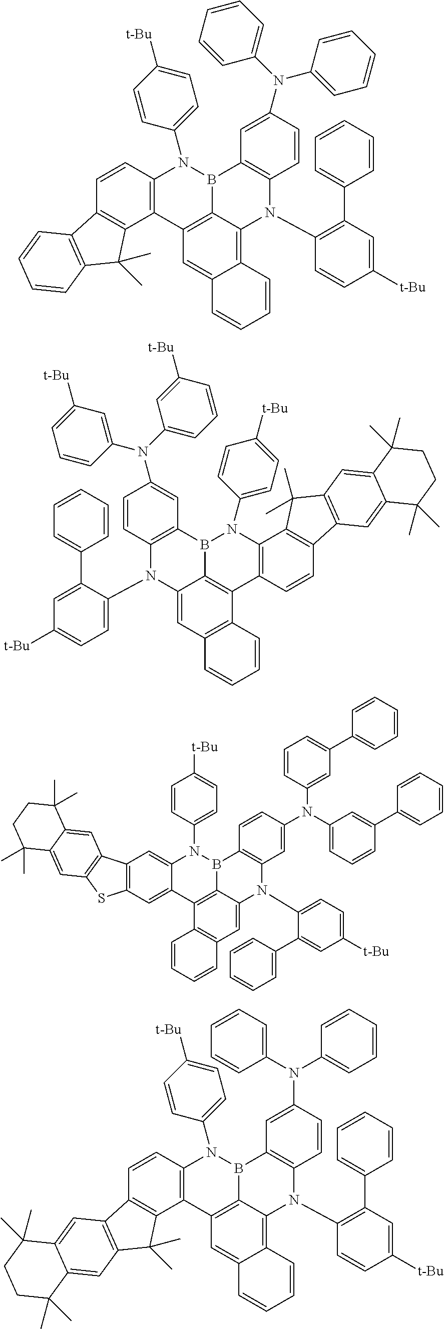 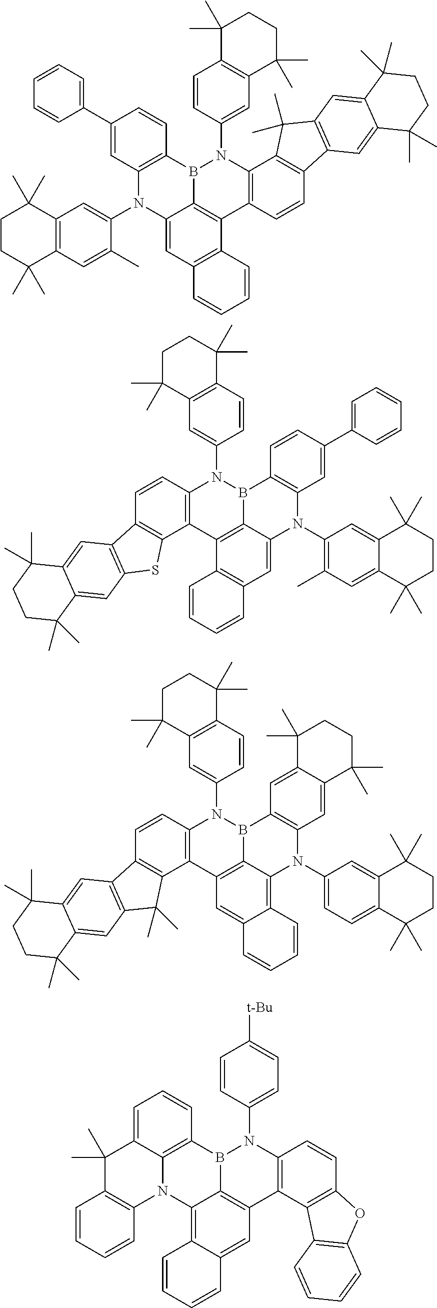 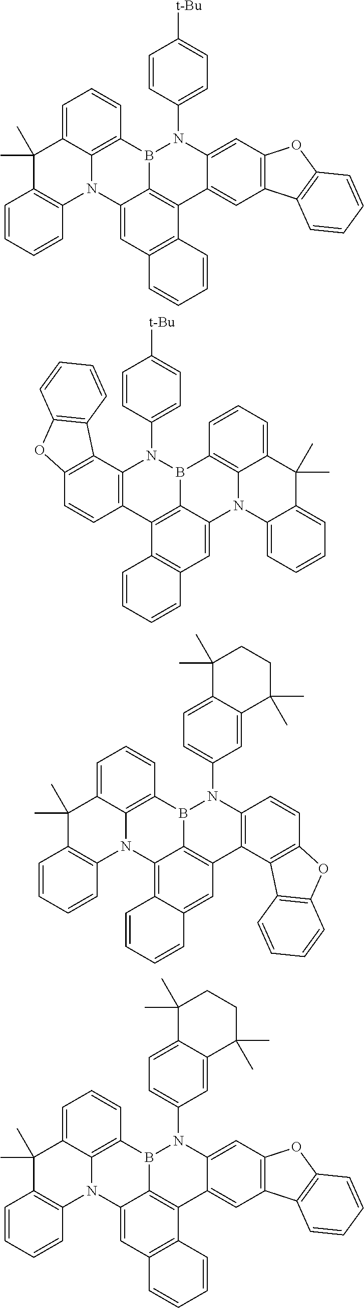 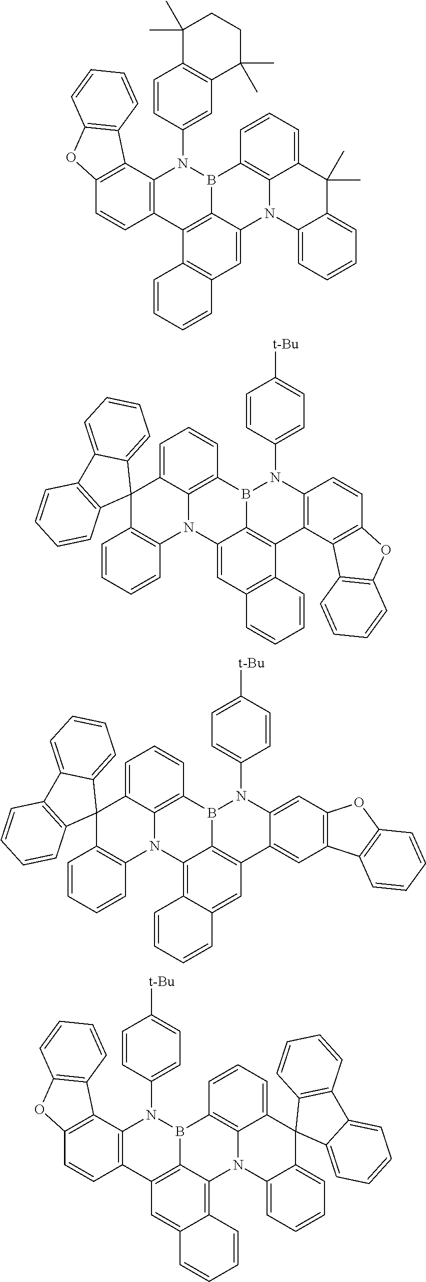 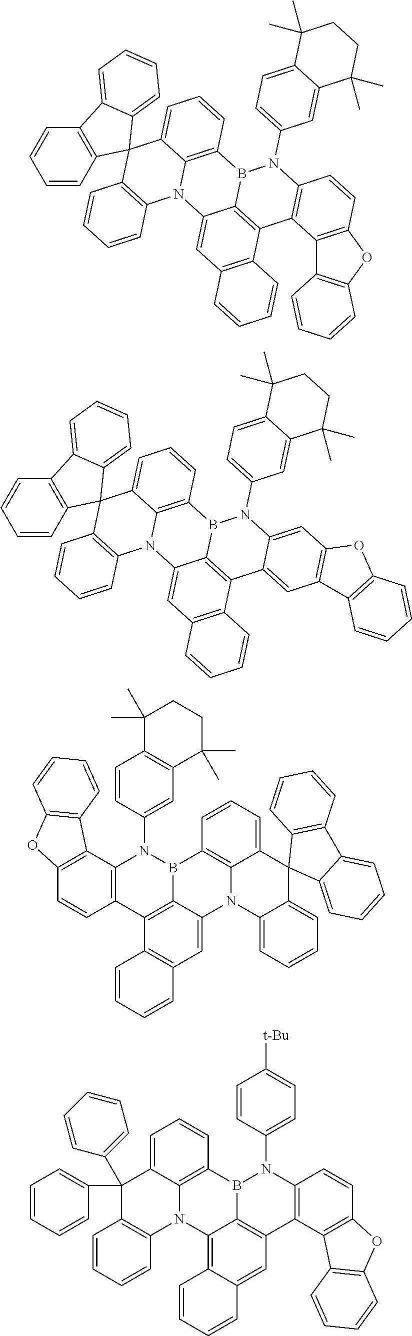 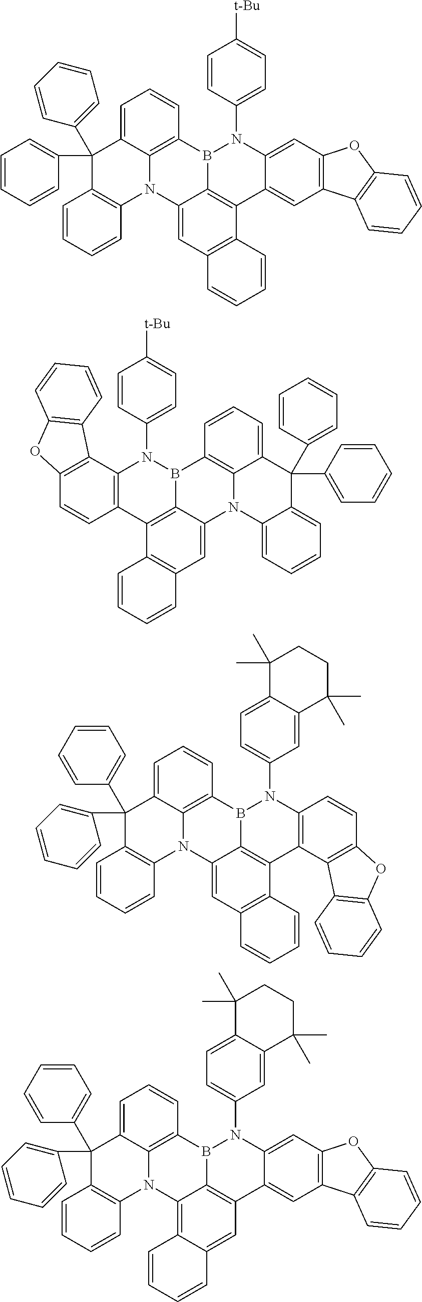 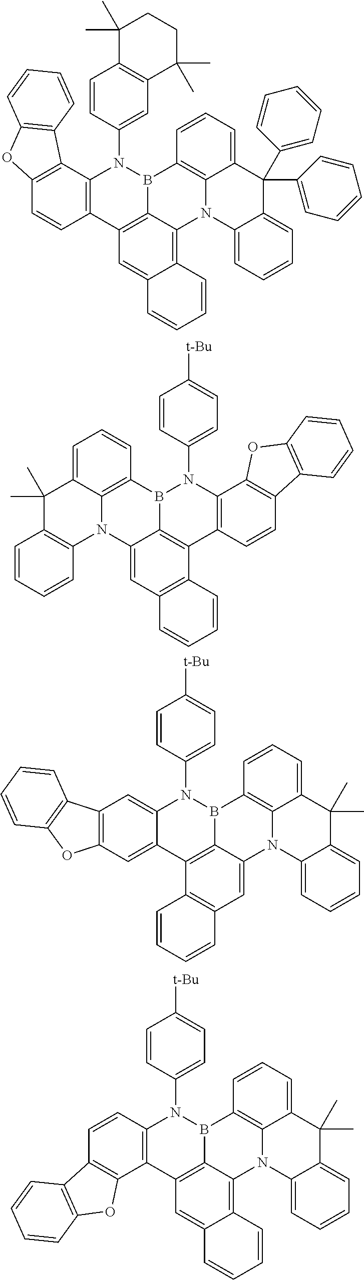 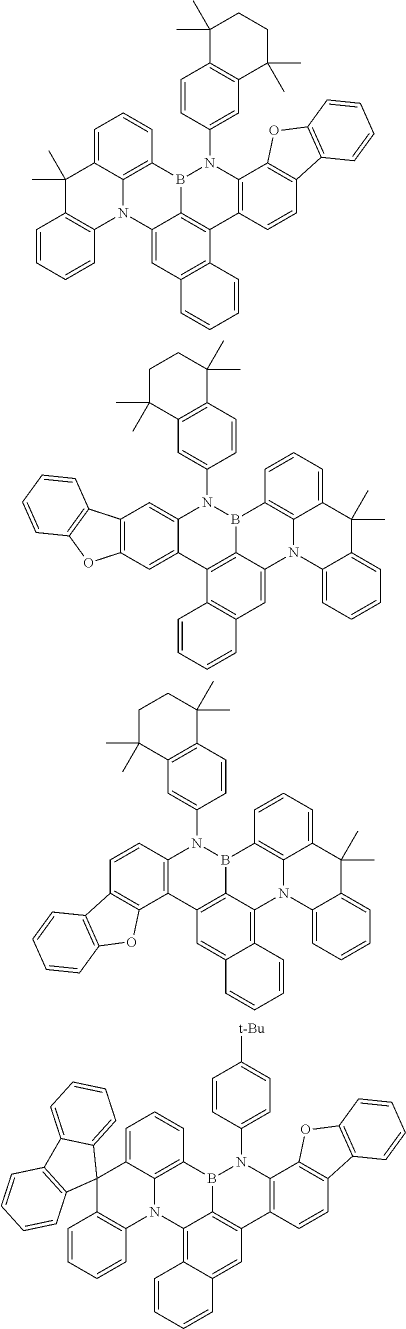 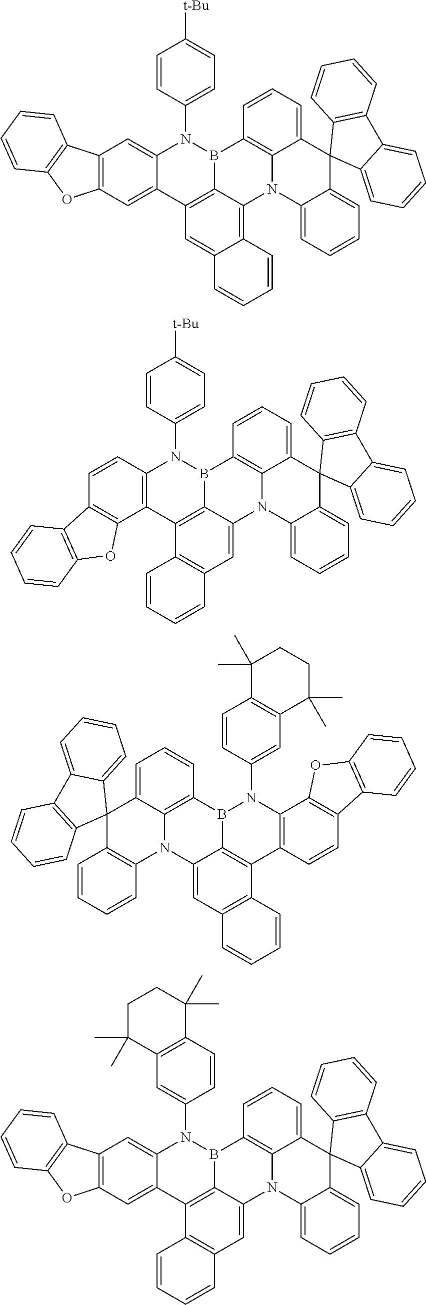 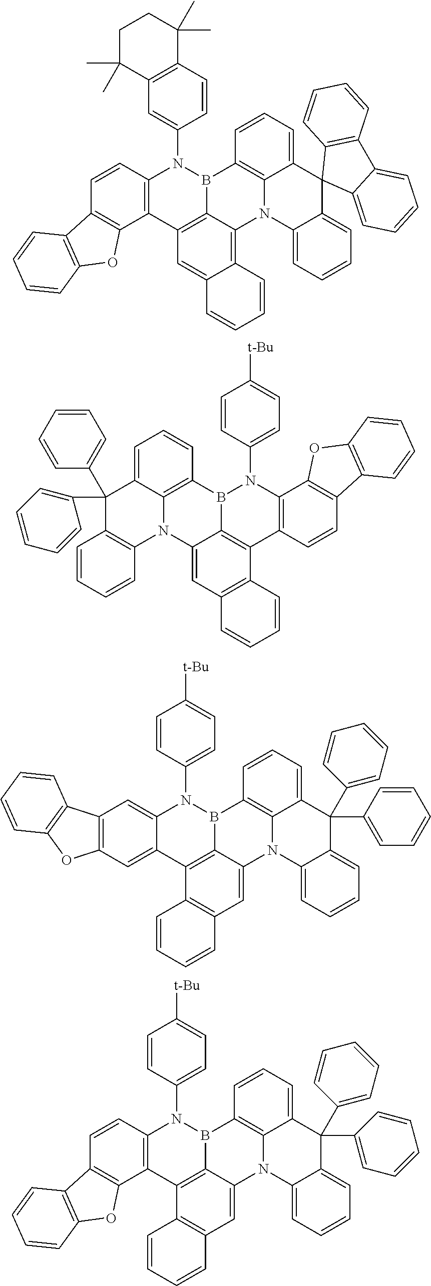 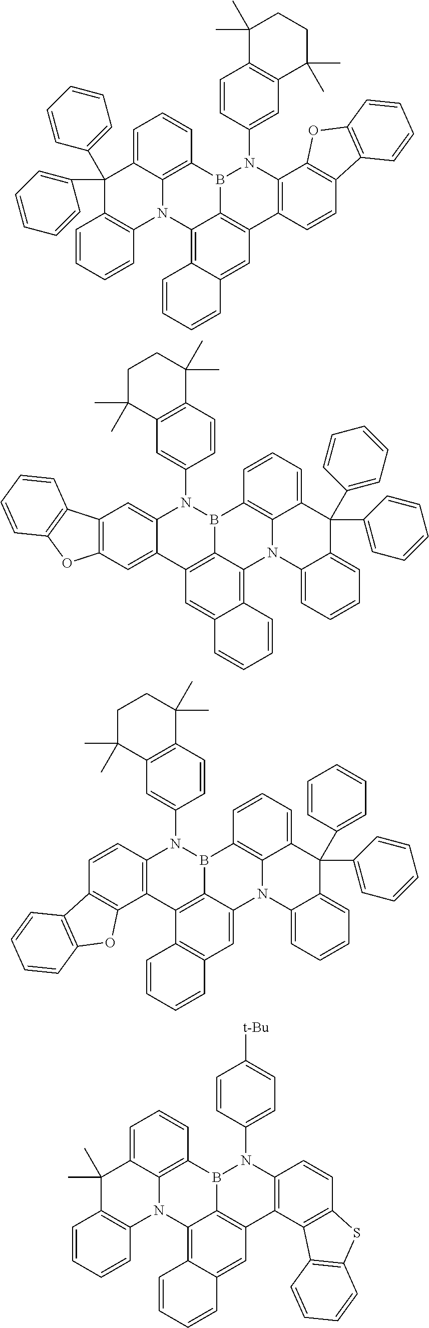 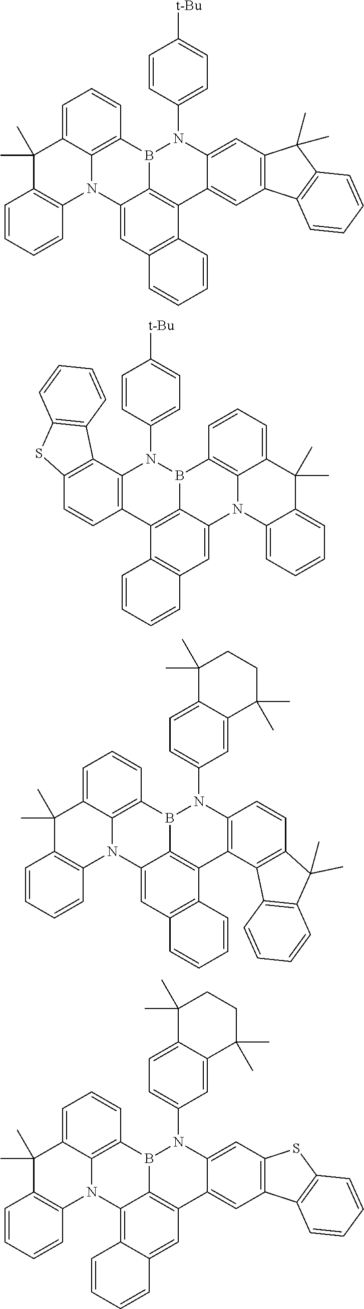 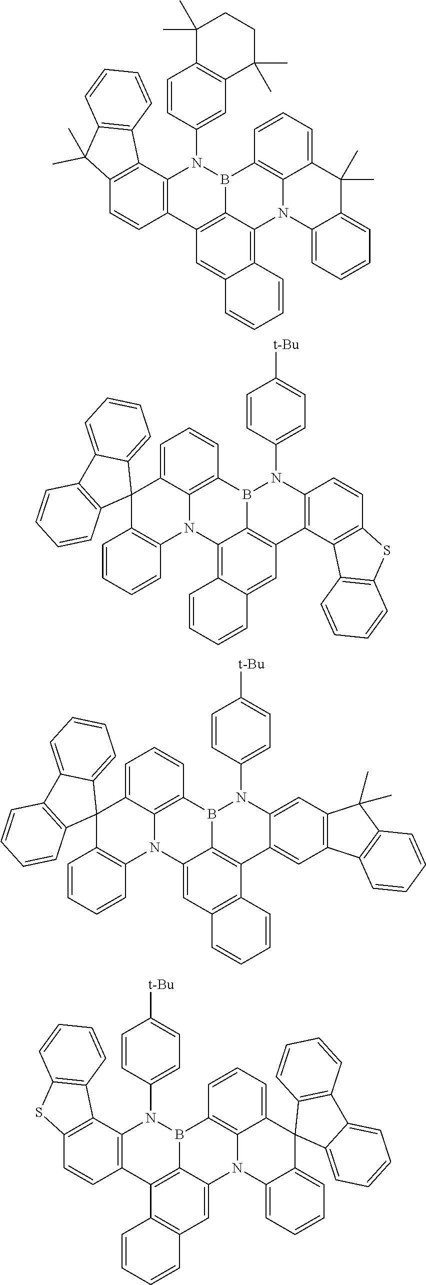 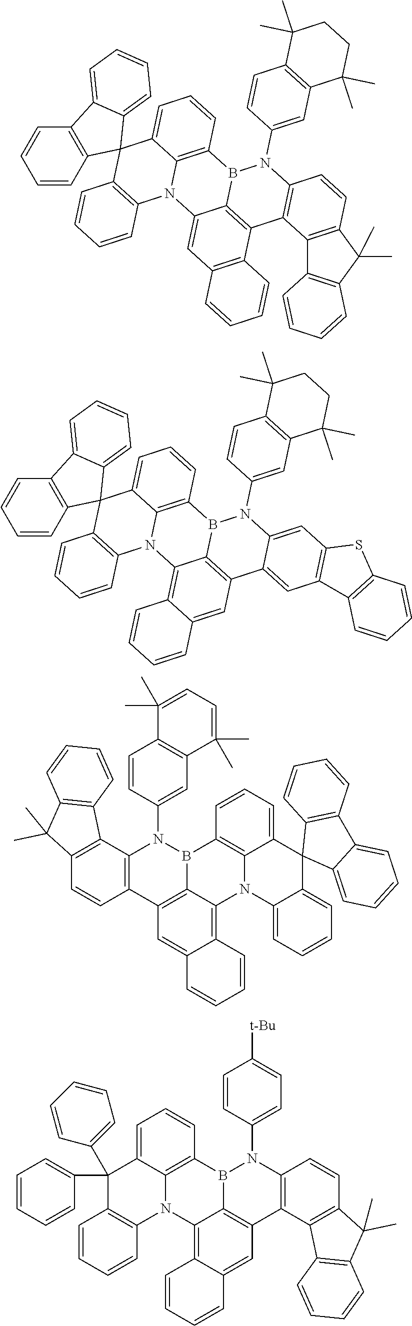 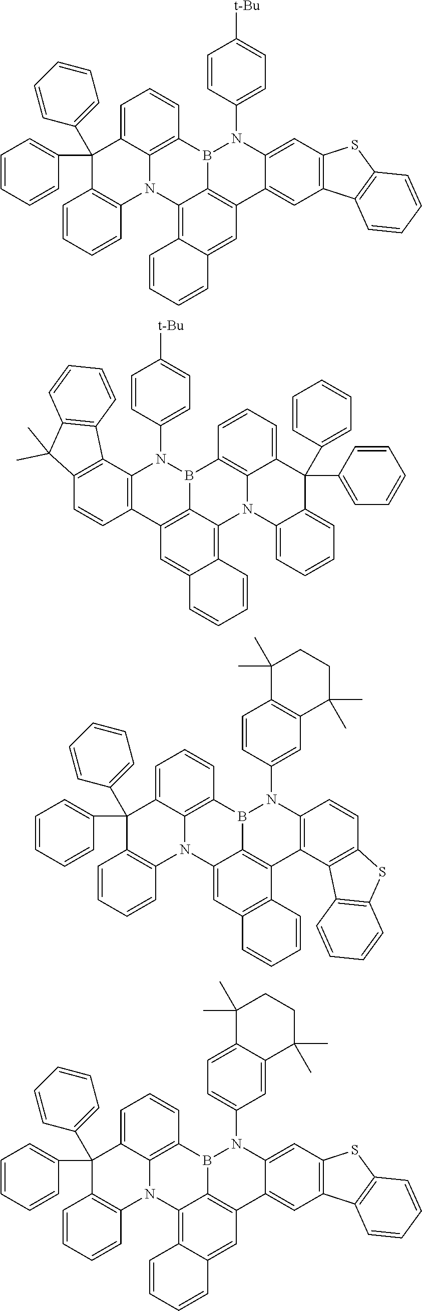 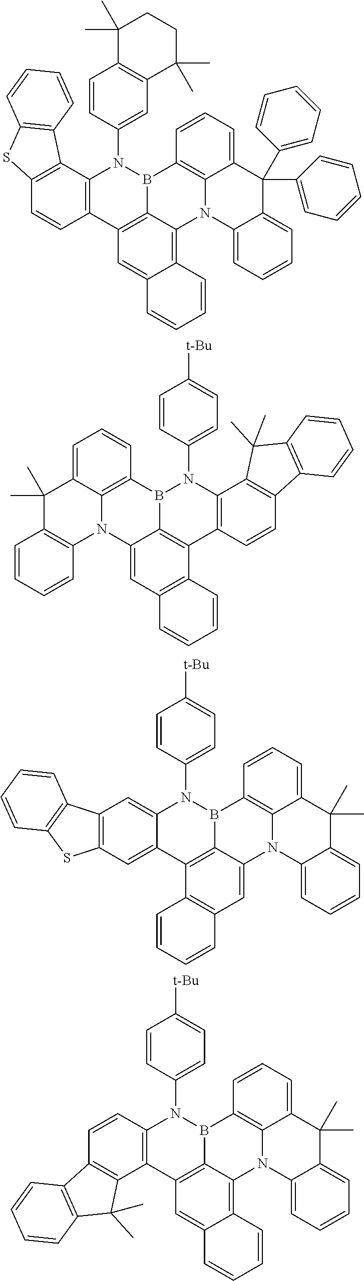 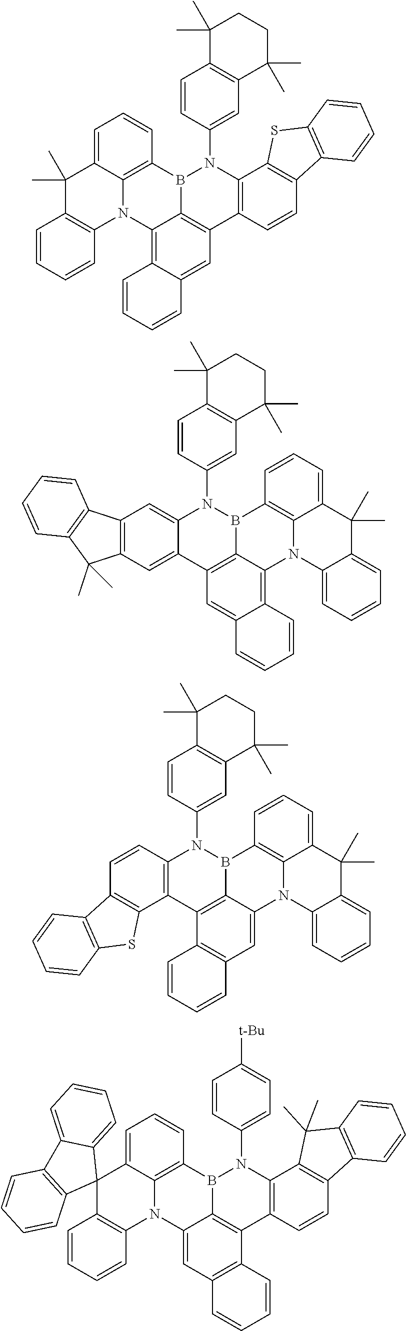 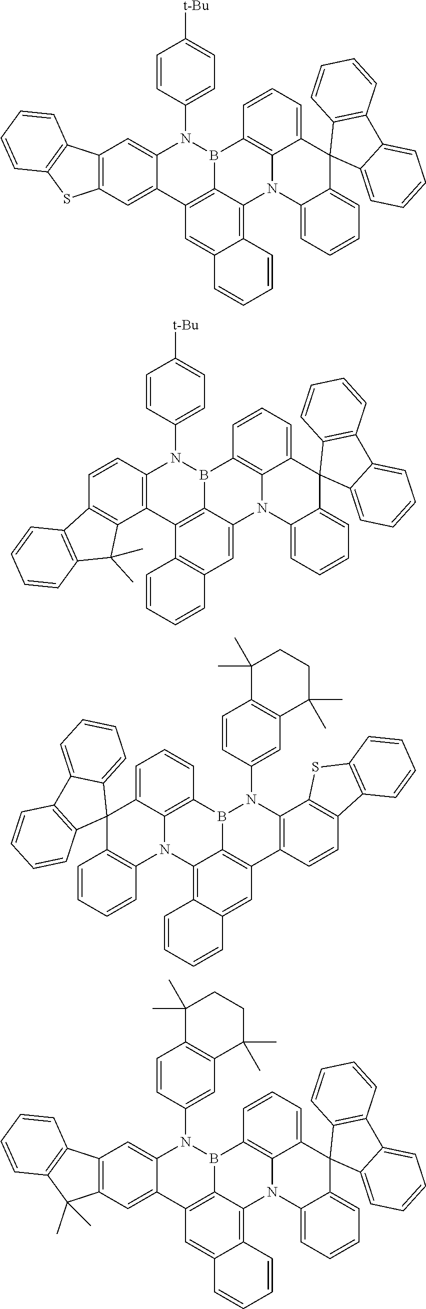 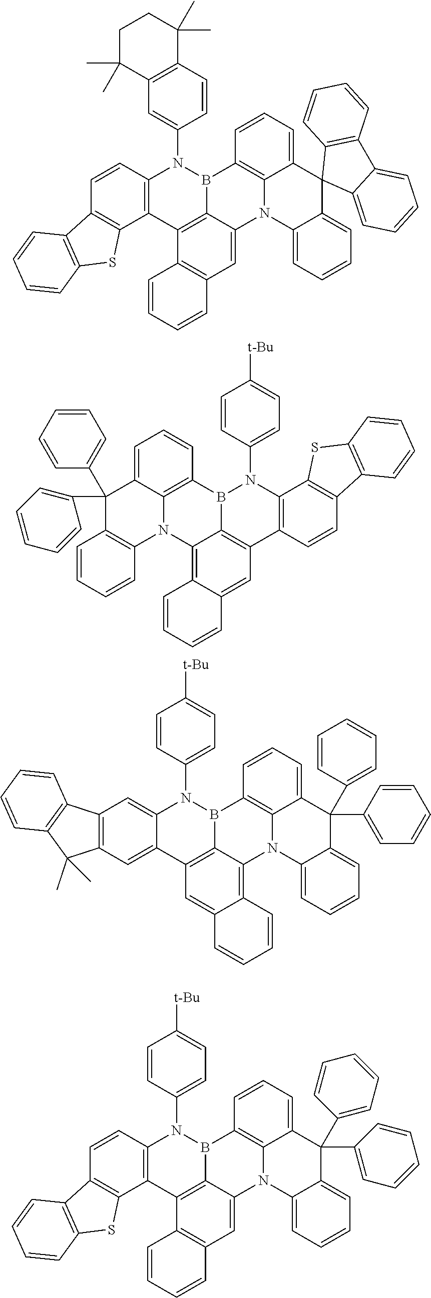 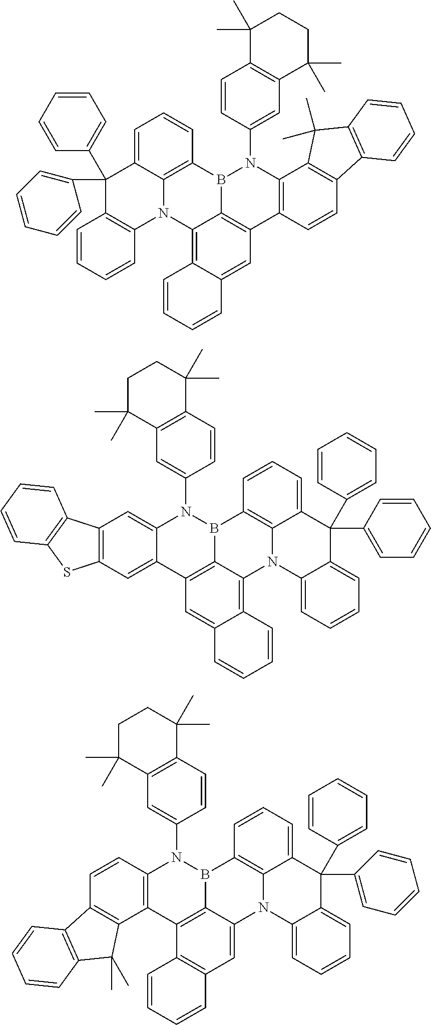 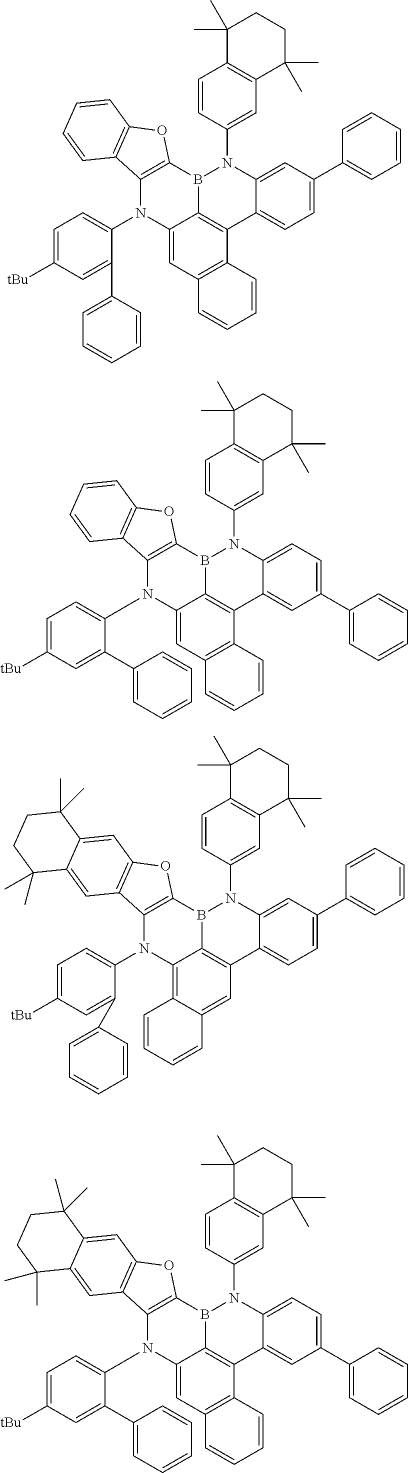 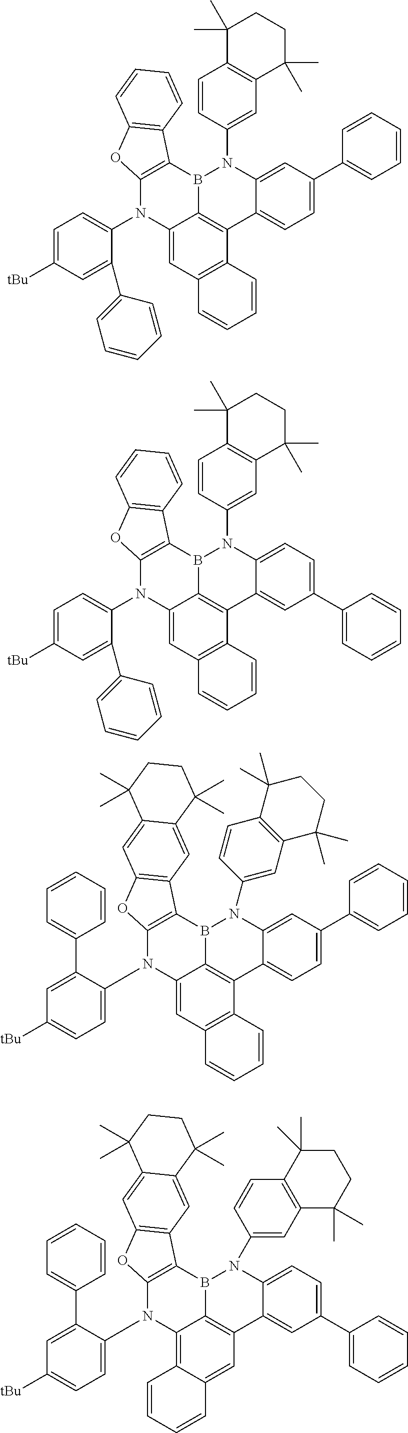 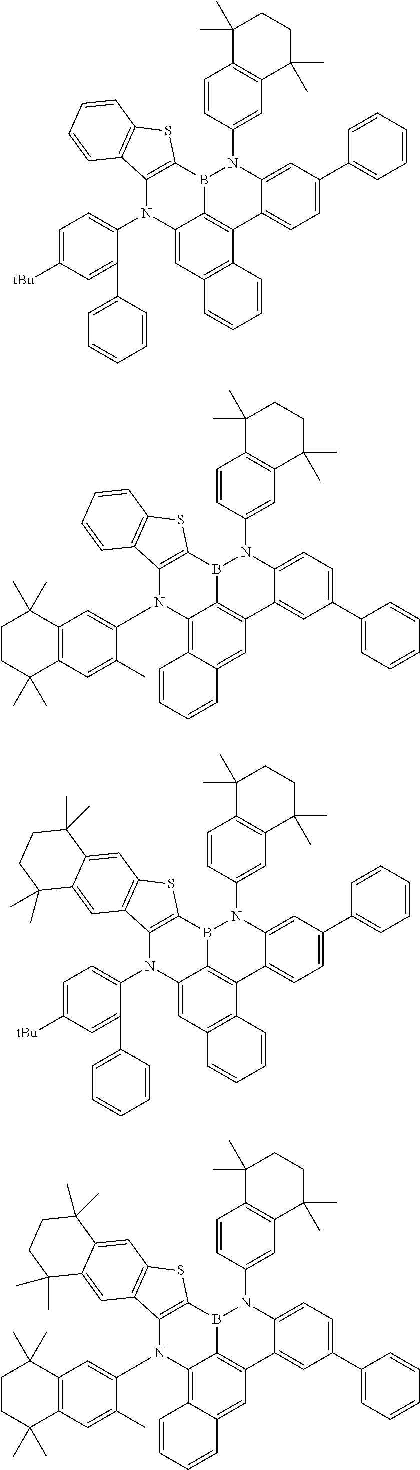 [SMILES: CC(C)(C)c1ccc(N2c3cc4ccccc4c4c3B(c3sc5ccccc5c32)N(c2ccc3c(c2)C(C)(C)CCC3(C)C)c2cc(-c3ccccc3)ccc2-4)c(-c2ccccc2)c1 ; Cc1cc2c(cc1N1c3c4c(cc5ccccc35)-c3cc(-c5ccccc5)ccc3N(c3ccc5c(c3)C(C)(C)CCC5(C)C)B4c3sc4ccccc4c31)C(C)(C)CCC2(C)C ; CC(C)(C)c1ccc(N2c3cc4ccccc4c4c3B(c3sc5cc6c(cc5c32)C(C)(C)CCC6(C)C)N(c2ccc3c(c2)C(C)(C)CCC3(C)C)c2cc(-c3ccccc3)ccc2-4)c(-c2ccccc2)c1 ; Cc1cc2c(cc1N1c3c4c(cc5ccccc35)-c3cc(-c5ccccc5)ccc3N(c3ccc5c(c3)C(C)(C)CCC5(C)C)B4c3sc4cc5c(cc4c31)C(C)(C)CCC5(C)C)C(C)(C)CCC2(C)C] 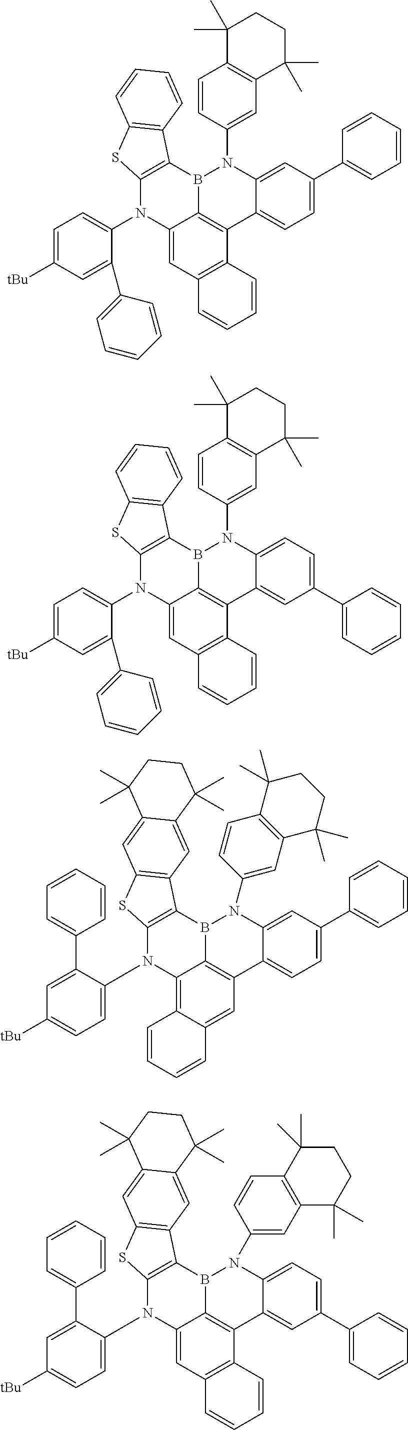 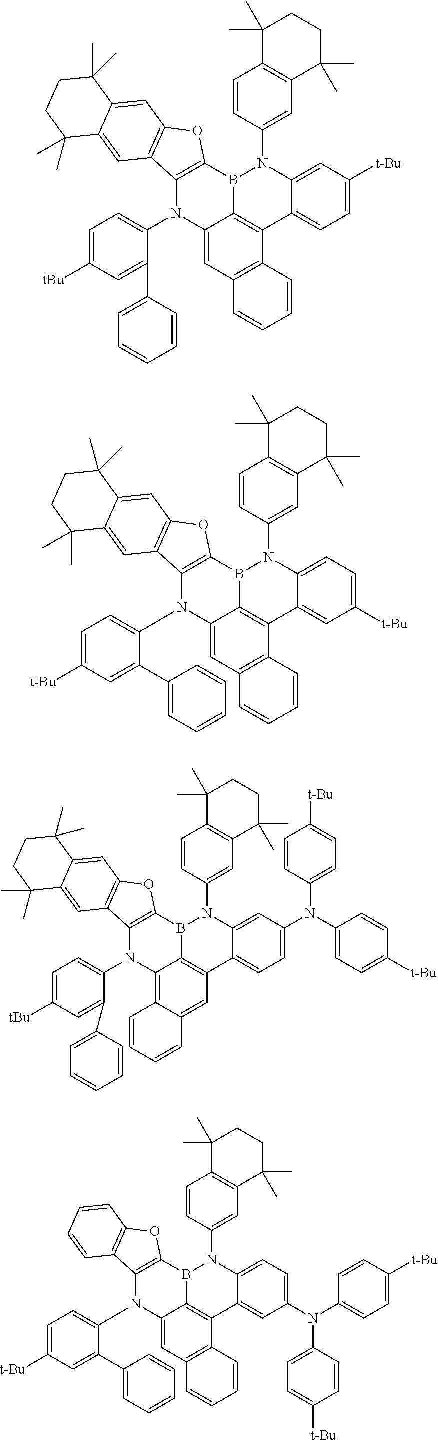 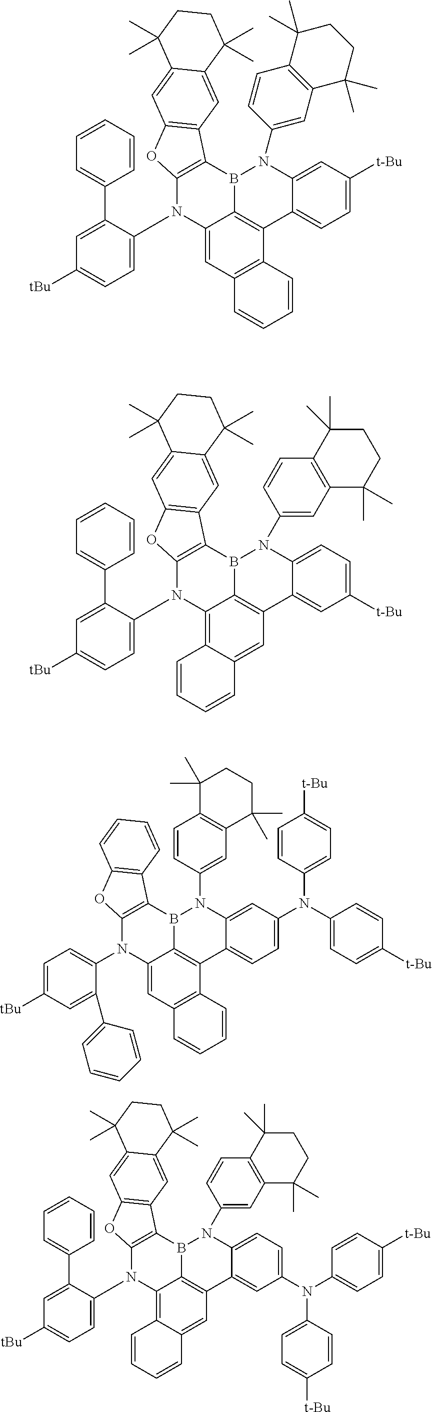 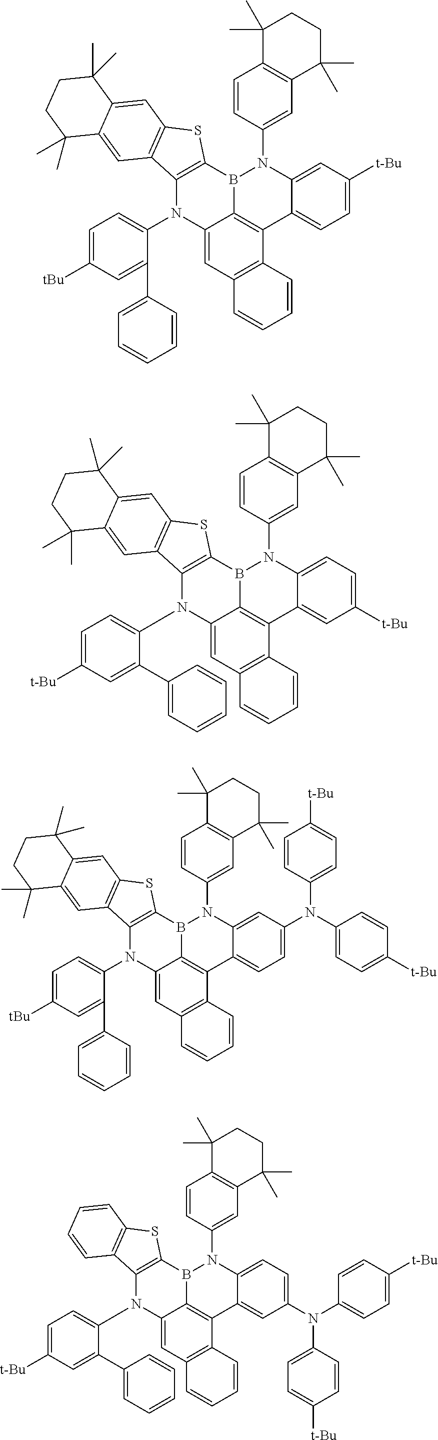 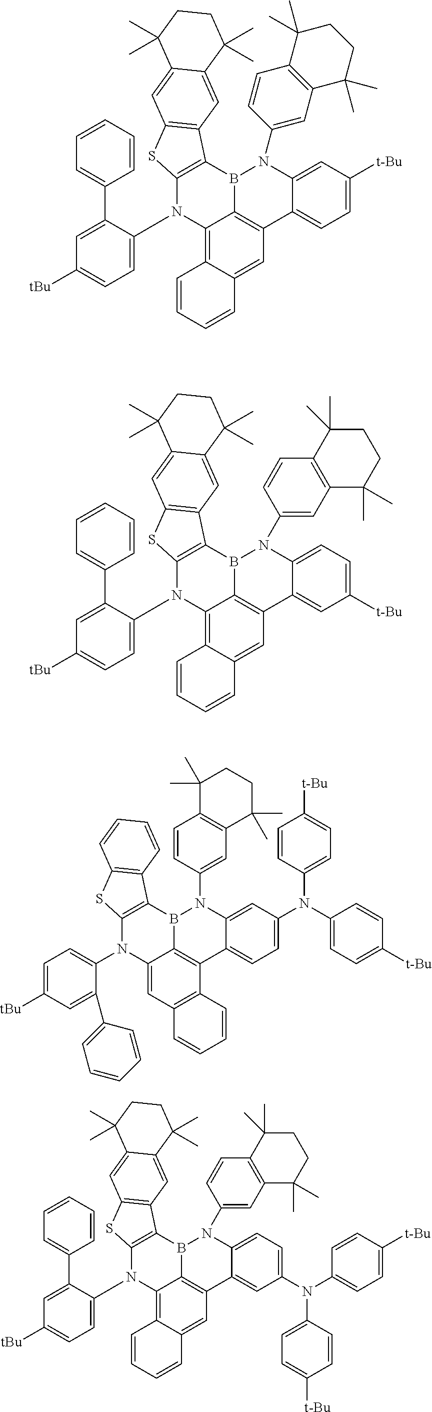 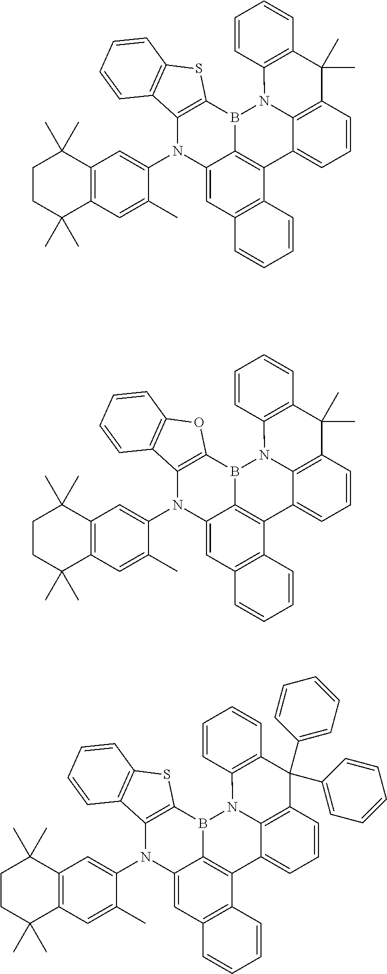 [SMILES: Cc1cc2c(cc1N1c3cc4ccccc4c4c3B(c3sc5ccccc5c31)N1c3ccccc3C(C)(C)c3cccc-4c31)C(C)(C)CCC2(C)C ; Cc1cc2c(cc1N1c3cc4ccccc4c4c3B(c3oc5ccccc5c31)N1c3ccccc3C(C)(C)c3cccc-4c31)C(C)(C)CCC2(C)C ; Cc1cc2c(cc1N1c3cc4ccccc4c4c3B(c3sc5ccccc5c31)N1c3ccccc3C(c3ccccc3)(c3ccccc3)c3cccc-4c31)C(C)(C)CCC2(C)C] 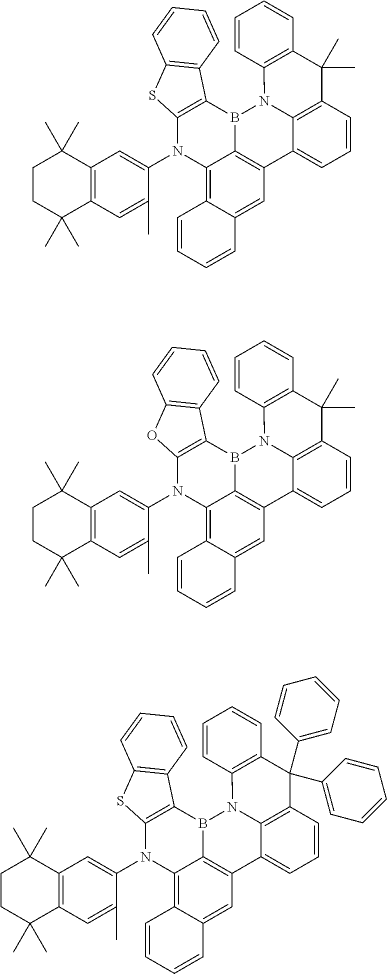 [SMILES: Cc1cc2c(cc1N1c3sc4ccccc4c3B3c4c(cc5ccccc5c41)-c1cccc4c1N3c1ccccc1C4(C)C)C(C)(C)CCC2(C)C ; Cc1cc2c(cc1N1c3oc4ccccc4c3B3c4c(cc5ccccc5c41)-c1cccc4c1N3c1ccccc1C4(C)C)C(C)(C)CCC2(C)C ; Cc1cc2c(cc1N1c3sc4ccccc4c3B3c4c(cc5ccccc5c41)-c1cccc4c1N3c1ccccc1C4(c1ccccc1)c1ccccc1)C(C)(C)CCC2(C)C] 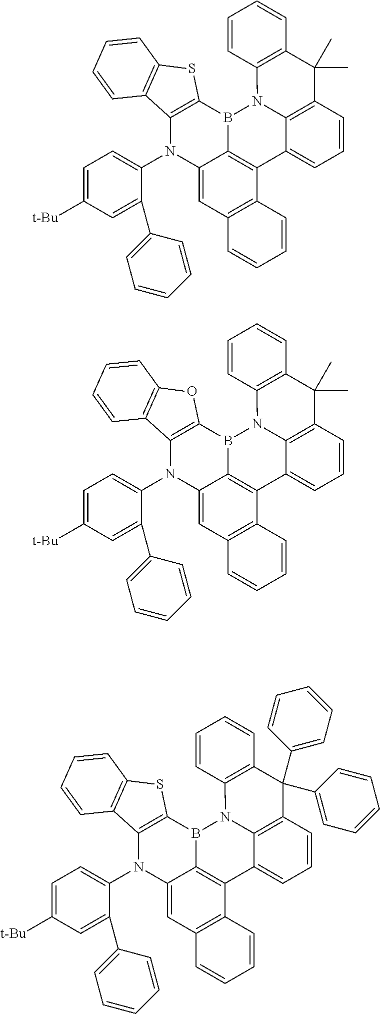 [SMILES: CC(C)(C)c1ccc(N2c3cc4ccccc4c4c3B(c3sc5ccccc5c32)N2c3ccccc3C(C)(C)c3cccc-4c32)c(-c2ccccc2)c1 ; CC(C)(C)c1ccc(N2c3cc4ccccc4c4c3B(c3oc5ccccc5c32)N2c3ccccc3C(C)(C)c3cccc-4c32)c(-c2ccccc2)c1 ; CC(C)(C)c1ccc(N2c3cc4ccccc4c4c3B(c3sc5ccccc5c32)N2c3ccccc3C(c3ccccc3)(c3ccccc3)c3cccc-4c32)c(-c2ccccc2)c1] 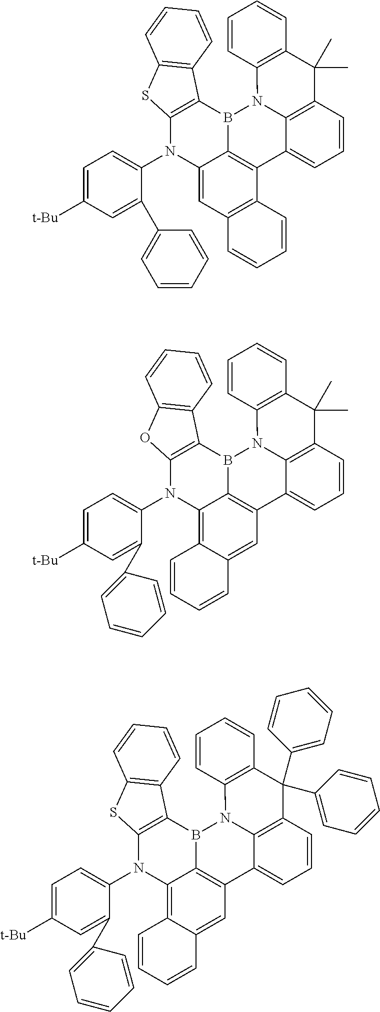 [SMILES: CC(C)(C)c1ccc(N2c3cc4ccccc4c4c3B(c3c2sc2ccccc32)N2c3ccccc3C(C)(C)c3cccc-4c32)c(-c2ccccc2)c1 ; CC(C)(C)c1ccc(N2c3oc4ccccc4c3B3c4c(cc5ccccc5c42)-c2cccc4c2N3c2ccccc2C4(C)C)c(-c2ccccc2)c1 ; CC(C)(C)c1ccc(N2c3sc4ccccc4c3B3c4c(cc5ccccc5c42)-c2cccc4c2N3c2ccccc2C4(c2ccccc2)c2ccccc2)c(-c2ccccc2)c1] 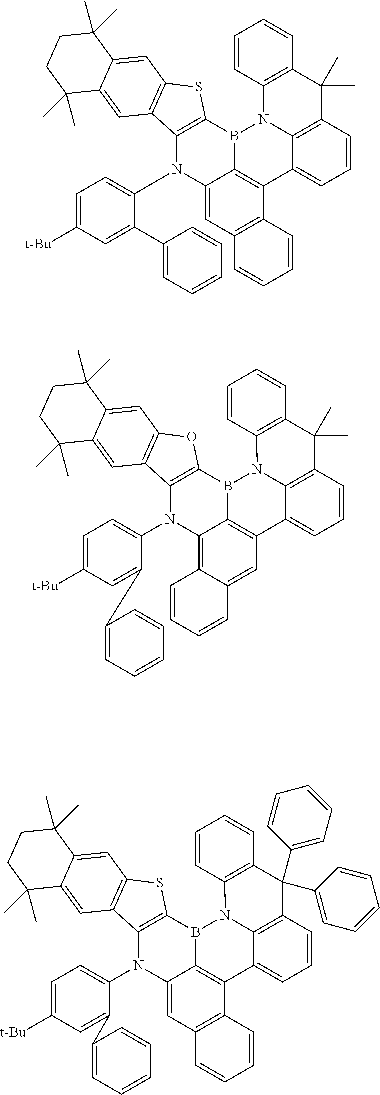 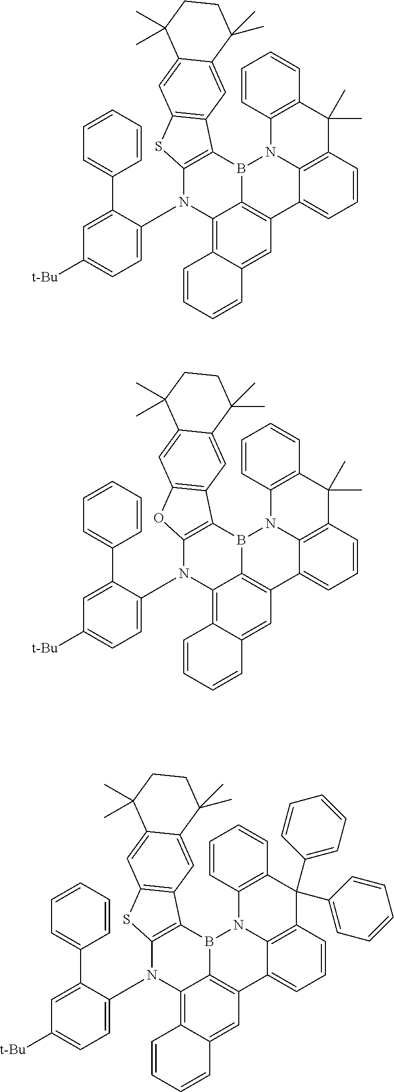 [SMILES: CC(C)(C)c1ccc(N2c3sc4cc5c(cc4c3B3c4c(cc6ccccc6c42)-c2cccc4c2N3c2ccccc2C4(C)C)C(C)(C)CCC5(C)C)c(-c2ccccc2)c1 ; CC(C)(C)c1ccc(N2c3oc4cc5c(cc4c3B3c4c(cc6ccccc6c42)-c2cccc4c2N3c2ccccc2C4(C)C)C(C)(C)CCC5(C)C)c(-c2ccccc2)c1 ; CC(C)(C)c1ccc(N2c3sc4cc5c(cc4c3B3c4c(cc6ccccc6c42)-c2cccc4c2N3c2ccccc2C4(c2ccccc2)c2ccccc2)C(C)(C)CCC5(C)C)c(-c2ccccc2)c1] 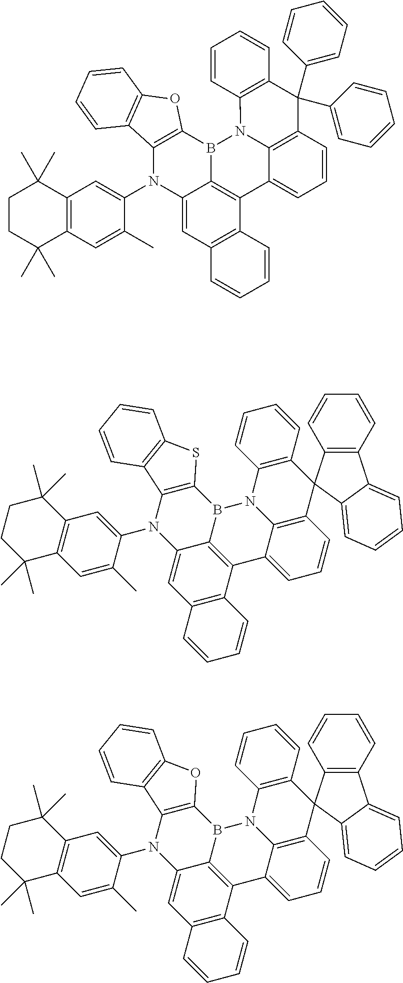 [SMILES: Cc1cc2c(cc1N1c3cc4ccccc4c4c3B(c3oc5ccccc5c31)N1c3ccccc3C(c3ccccc3)(c3ccccc3)c3cccc-4c31)C(C)(C)CCC2(C)C ; Cc1cc2c(cc1N1c3cc4ccccc4c4c3B(c3sc5ccccc5c31)N1c3ccccc3C3(c5ccccc5-c5ccccc53)c3cccc-4c31)C(C)(C)CCC2(C)C ; Cc1cc2c(cc1N1c3cc4ccccc4c4c3B(c3oc5ccccc5c31)N1c3ccccc3C3(c5ccccc5-c5ccccc53)c3cccc-4c31)C(C)(C)CCC2(C)C] 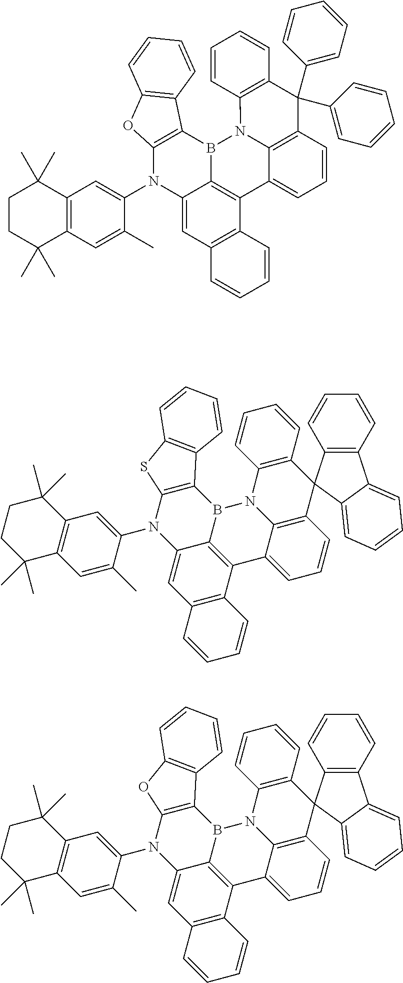 [SMILES: Cc1cc2c(cc1N1c3cc4ccccc4c4c3B(c3c1oc1ccccc31)N1c3ccccc3C(c3ccccc3)(c3ccccc3)c3cccc-4c31)C(C)(C)CCC2(C)C ; Cc1cc2c(cc1N1c3cc4ccccc4c4c3B(c3c1sc1ccccc31)N1c3ccccc3C3(c5ccccc5-c5ccccc53)c3cccc-4c31)C(C)(C)CCC2(C)C ; Cc1cc2c(cc1N1c3cc4ccccc4c4c3B(c3c1oc1ccccc31)N1c3ccccc3C3(c5ccccc5-c5ccccc53)c3cccc-4c31)C(C)(C)CCC2(C)C] 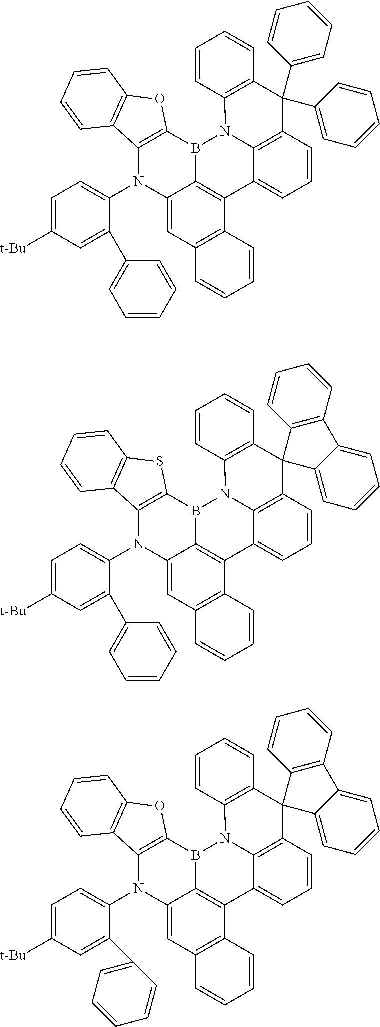 [SMILES: CC(C)(C)c1ccc(N2c3cc4ccccc4c4c3B(c3oc5ccccc5c32)N2c3ccccc3C(c3ccccc3)(c3ccccc3)c3cccc-4c32)c(-c2ccccc2)c1 ; CC(C)(C)c1ccc(N2c3cc4ccccc4c4c3B(c3sc5ccccc5c32)N2c3ccccc3C3(c5ccccc5-c5ccccc53)c3cccc-4c32)c(-c2ccccc2)c1 ; CC(C)(C)c1ccc(N2c3cc4ccccc4c4c3B(c3oc5ccccc5c32)N2c3ccccc3C3(c5ccccc5-c5ccccc53)c3cccc-4c32)c(-c2ccccc2)c1] 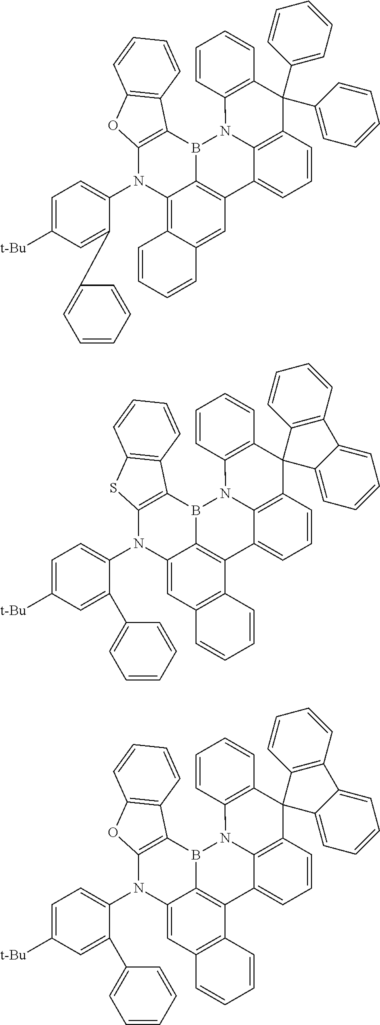 [SMILES: CC(C)(C)c1ccc(N2c3oc4ccccc4c3B3c4c(cc5ccccc5c42)-c2cccc4c2N3c2ccccc2C4(c2ccccc2)c2ccccc2)c(-c2ccccc2)c1 ; CC(C)(C)c1ccc(N2c3cc4ccccc4c4c3B(c3c2sc2ccccc32)N2c3ccccc3C3(c5ccccc5-c5ccccc53)c3cccc-4c32)c(-c2ccccc2)c1 ; CC(C)(C)c1ccc(N2c3cc4ccccc4c4c3B(c3c2oc2ccccc32)N2c3ccccc3C3(c5ccccc5-c5ccccc53)c3cccc-4c32)c(-c2ccccc2)c1] 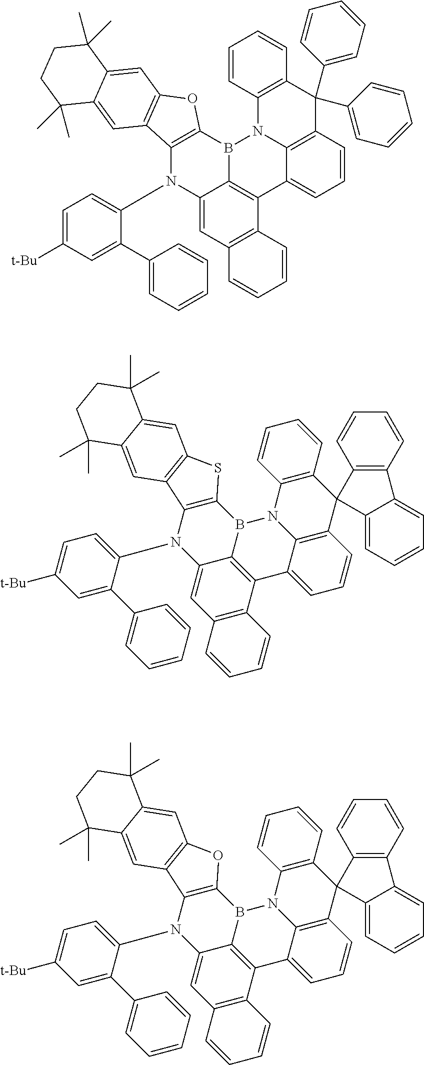 [SMILES: CC(C)(C)c1ccc(N2c3cc4ccccc4c4c3B(c3oc5cc6c(cc5c32)C(C)(C)CCC6(C)C)N2c3ccccc3C(c3ccccc3)(c3ccccc3)c3cccc-4c32)c(-c2ccccc2)c1 ; CC(C)(C)c1ccc(N2c3cc4ccccc4c4c3B(c3sc5cc6c(cc5c32)C(C)(C)CCC6(C)C)N2c3ccccc3C3(c5ccccc5-c5ccccc53)c3cccc-4c32)c(-c2ccccc2)c1 ; CC(C)(C)c1ccc(N2c3cc4ccccc4c4c3B(c3oc5cc6c(cc5c32)C(C)(C)CCC6(C)C)N2c3ccccc3C3(c5ccccc5-c5ccccc53)c3cccc-4c32)c(-c2ccccc2)c1] 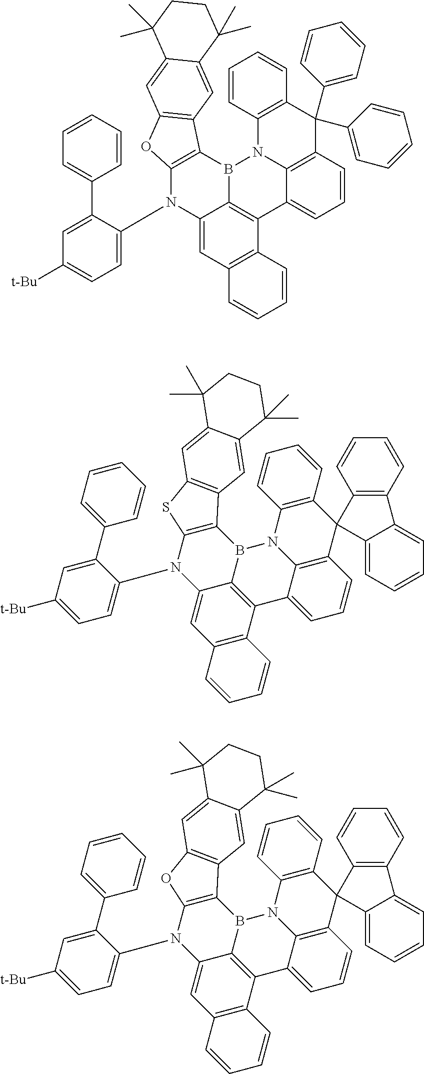 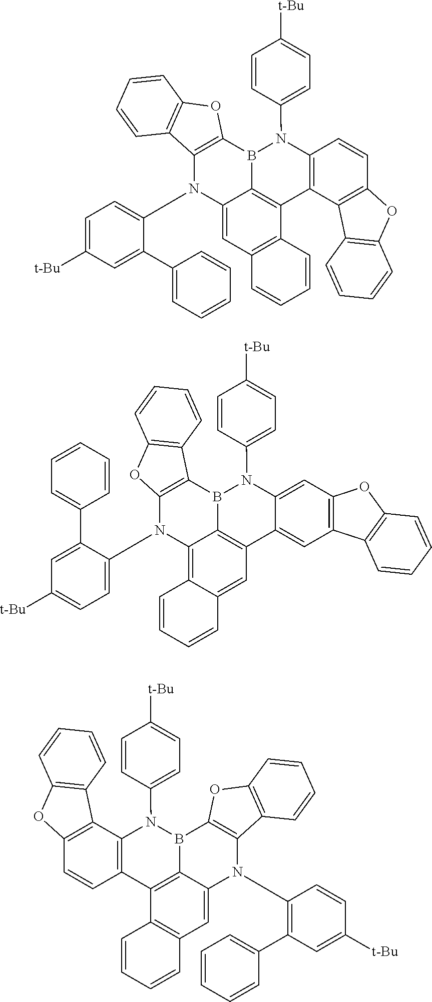 [SMILES: CC(C)(C)c1ccc(N2B3c4oc5ccccc5c4N(c4ccc(C(C)(C)C)cc4-c4ccccc4)c4cc5ccccc5c(c43)-c3c2ccc2oc4ccccc4c32)cc1 ; CC(C)(C)c1ccc(N2B3c4c(cc5ccccc5c4N(c4ccc(C(C)(C)C)cc4-c4ccccc4)c4oc5ccccc5c43)-c3cc4c(cc32)oc2ccccc24)cc1 ; CC(C)(C)c1ccc(N2B3c4oc5ccccc5c4N(c4ccc(C(C)(C)C)cc4-c4ccccc4)c4cc5ccccc5c(c43)-c3ccc4oc5ccccc5c4c32)cc1] 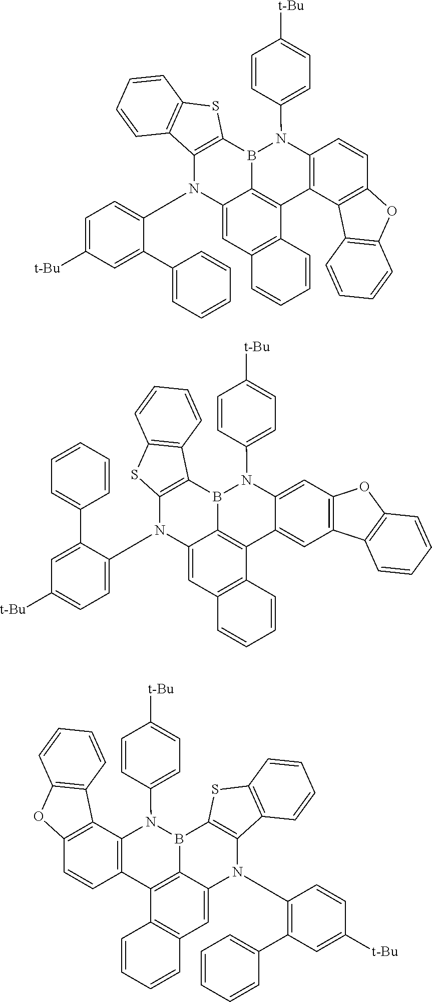 [SMILES: CC(C)(C)c1ccc(N2B3c4sc5ccccc5c4N(c4ccc(C(C)(C)C)cc4-c4ccccc4)c4cc5ccccc5c(c43)-c3c2ccc2oc4ccccc4c32)cc1 ; CC(C)(C)c1ccc(N2B3c4c(cc5ccccc5c4-c4cc5c(cc42)oc2ccccc25)N(c2ccc(C(C)(C)C)cc2-c2ccccc2)c2sc4ccccc4c23)cc1 ; CC(C)(C)c1ccc(N2B3c4sc5ccccc5c4N(c4ccc(C(C)(C)C)cc4-c4ccccc4)c4cc5ccccc5c(c43)-c3ccc4oc5ccccc5c4c32)cc1] 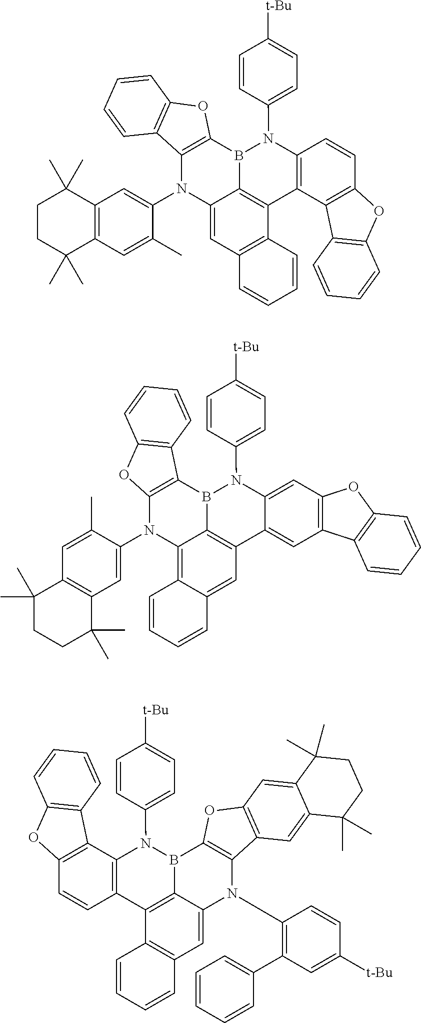 [SMILES: Cc1cc2c(cc1N1c3cc4ccccc4c4c3B(c3oc5ccccc5c31)N(c1ccc(C(C)(C)C)cc1)c1ccc3oc5ccccc5c3c1-4)C(C)(C)CCC2(C)C ; Cc1cc2c(cc1N1c3oc4ccccc4c3B3c4c(cc5ccccc5c41)-c1cc4c(cc1N3c1ccc(C(C)(C)C)cc1)oc1ccccc14)C(C)(C)CCC2(C)C ; CC(C)(C)c1ccc(N2B3c4oc5cc6c(cc5c4N(c4ccc(C(C)(C)C)cc4-c4ccccc4)c4cc5ccccc5c(c43)-c3ccc4oc5ccccc5c4c32)C(C)(C)CCC6(C)C)cc1] 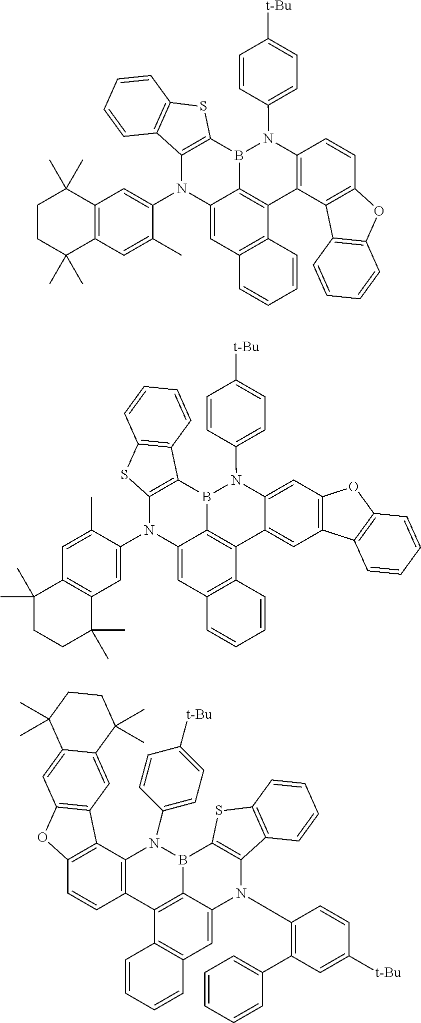 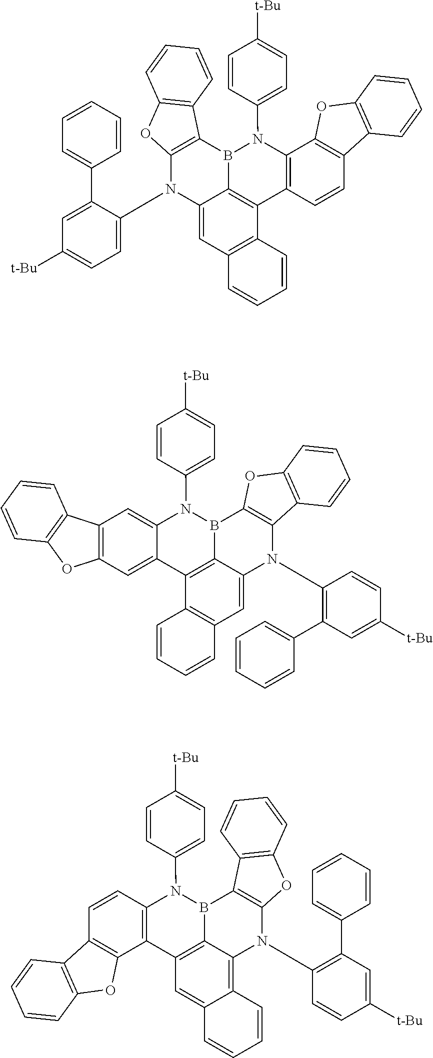 [SMILES: CC(C)(C)c1ccc(N2B3c4c(cc5ccccc5c4-c4ccc5c(oc6ccccc65)c42)N(c2ccc(C(C)(C)C)cc2-c2ccccc2)c2oc4ccccc4c23)cc1 ; CC(C)(C)c1ccc(N2B3c4oc5ccccc5c4N(c4ccc(C(C)(C)C)cc4-c4ccccc4)c4cc5ccccc5c(c43)-c3cc4oc5ccccc5c4cc32)cc1 ; CC(C)(C)c1ccc(N2B3c4c(cc5ccccc5c4N(c4ccc(C(C)(C)C)cc4-c4ccccc4)c4oc5ccccc5c43)-c3c2ccc2c3oc3ccccc32)cc1] 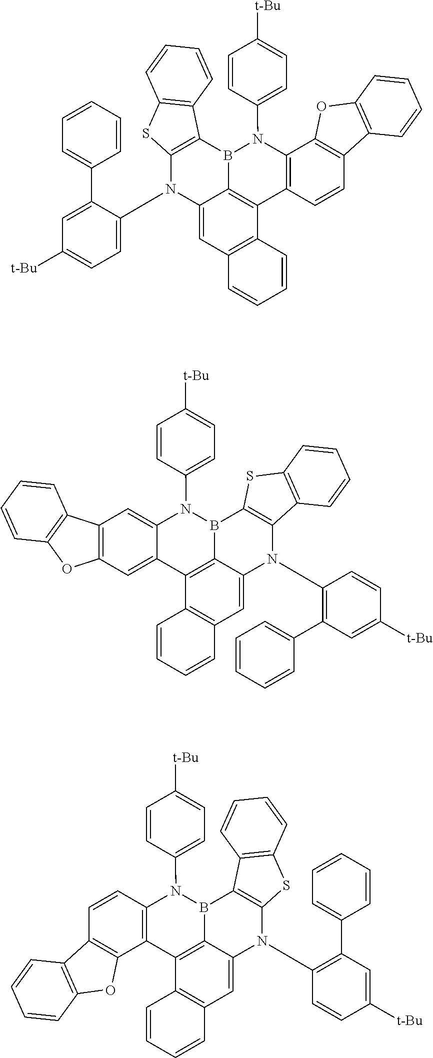 [SMILES: CC(C)(C)c1ccc(N2B3c4c(cc5ccccc5c4-c4ccc5c(oc6ccccc65)c42)N(c2ccc(C(C)(C)C)cc2-c2ccccc2)c2sc4ccccc4c23)cc1 ; CC(C)(C)c1ccc(N2B3c4sc5ccccc5c4N(c4ccc(C(C)(C)C)cc4-c4ccccc4)c4cc5ccccc5c(c43)-c3cc4oc5ccccc5c4cc32)cc1 ; CC(C)(C)c1ccc(N2B3c4c(cc5ccccc5c4-c4c2ccc2c4oc4ccccc42)N(c2ccc(C(C)(C)C)cc2-c2ccccc2)c2sc4ccccc4c23)cc1] 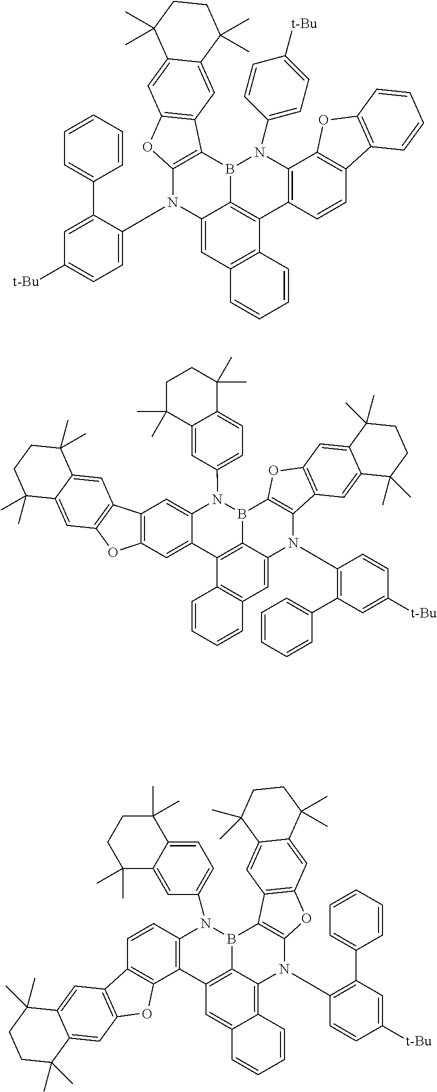 [SMILES: CC(C)(C)c1ccc(N2B3c4c(cc5ccccc5c4-c4ccc5c(oc6ccccc65)c42)N(c2ccc(C(C)(C)C)cc2-c2ccccc2)c2oc4cc5c(cc4c23)C(C)(C)CCC5(C)C)cc1 ; CC(C)(C)c1ccc(N2c3cc4ccccc4c4c3B(c3oc5cc6c(cc5c32)C(C)(C)CCC6(C)C)N(c2ccc3c(c2)C(C)(C)CCC3(C)C)c2cc3c(cc2-4)oc2cc4c(cc23)C(C)(C)CCC4(C)C)c(-c2ccccc2)c1 ; CC(C)(C)c1ccc(N2c3oc4cc5c(cc4c3B3c4c(cc6ccccc6c42)-c2c(ccc4c2oc2cc6c(cc24)C(C)(C)CCC6(C)C)N3c2ccc3c(c2)C(C)(C)CCC3(C)C)C(C)(C)CCC5(C)C)c(-c2ccccc2)c1] 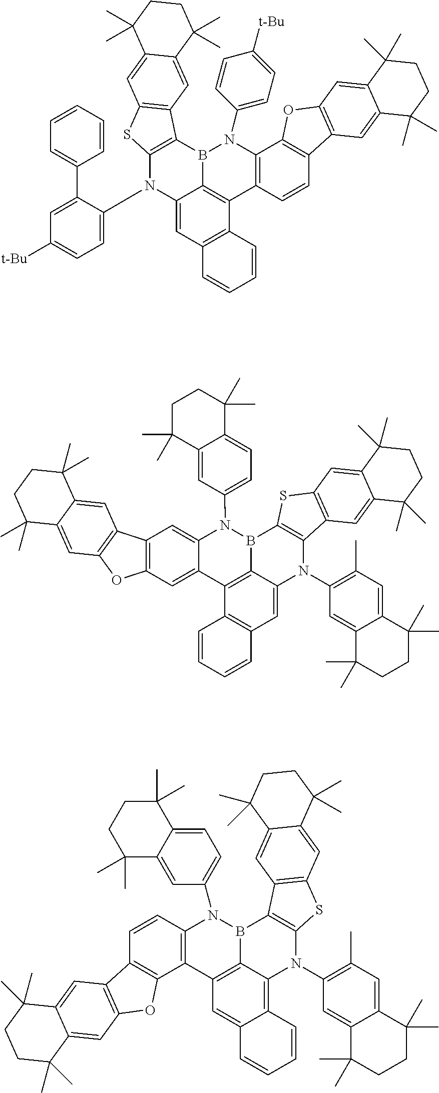 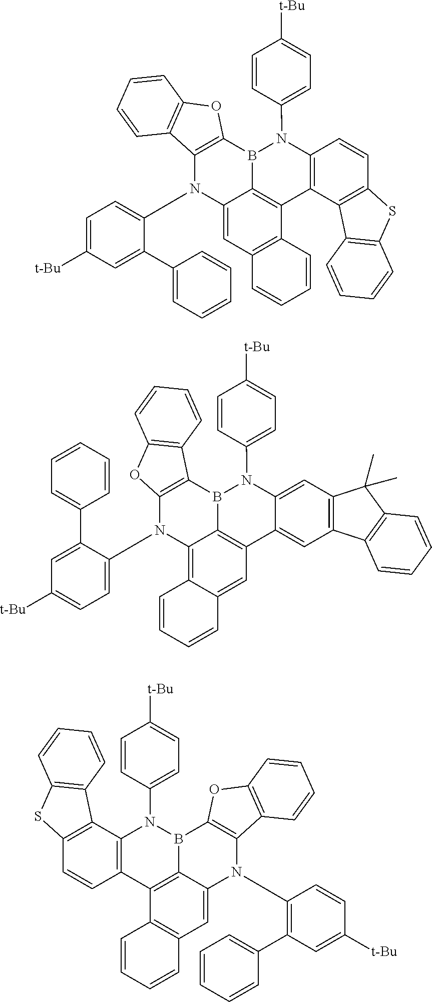 [SMILES: CC(C)(C)c1ccc(N2B3c4oc5ccccc5c4N(c4ccc(C(C)(C)C)cc4-c4ccccc4)c4cc5ccccc5c(c43)-c3c2ccc2sc4ccccc4c32)cc1 ; CC(C)(C)c1ccc(N2B3c4c(cc5ccccc5c4N(c4ccc(C(C)(C)C)cc4-c4ccccc4)c4oc5ccccc5c43)-c3cc4c(cc32)C(C)(C)c2ccccc2-4)cc1 ; CC(C)(C)c1ccc(N2B3c4oc5ccccc5c4N(c4ccc(C(C)(C)C)cc4-c4ccccc4)c4cc5ccccc5c(c43)-c3ccc4sc5ccccc5c4c32)cc1] 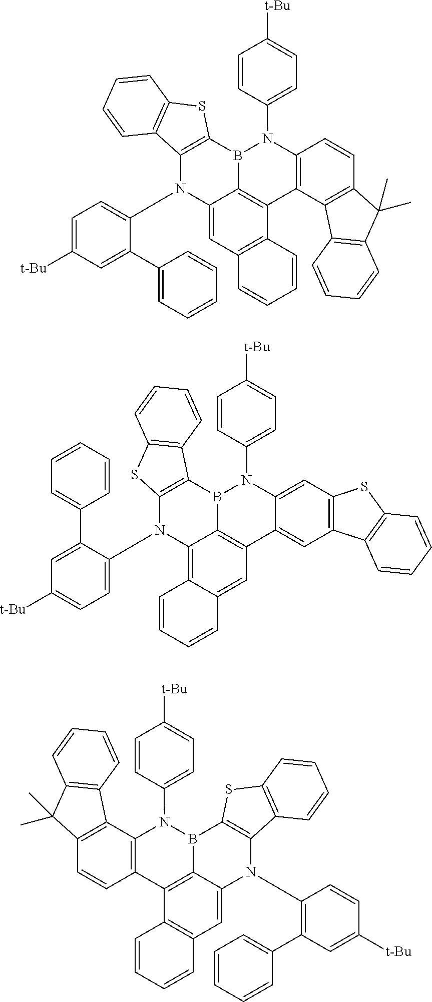 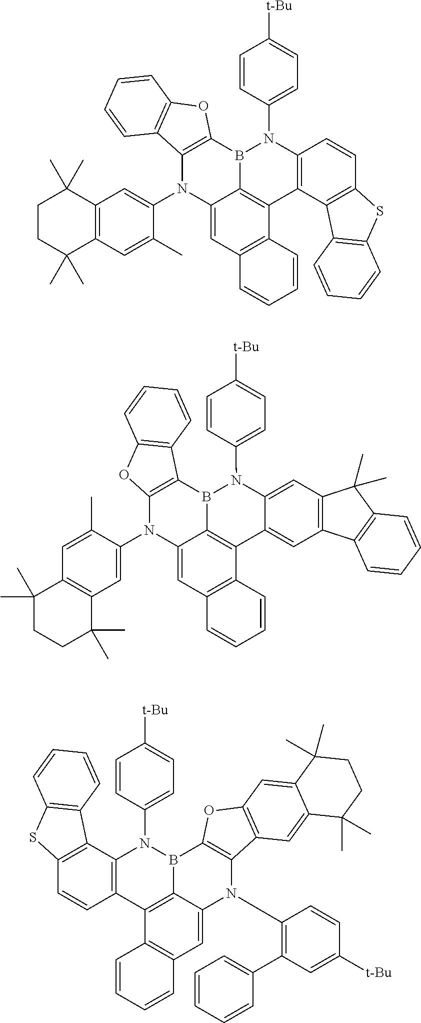 [SMILES: Cc1cc2c(cc1N1c3cc4ccccc4c4c3B(c3oc5ccccc5c31)N(c1ccc(C(C)(C)C)cc1)c1ccc3sc5ccccc5c3c1-4)C(C)(C)CCC2(C)C ; Cc1cc2c(cc1N1c3cc4ccccc4c4c3B(c3c1oc1ccccc31)N(c1ccc(C(C)(C)C)cc1)c1cc3c(cc1-4)-c1ccccc1C3(C)C)C(C)(C)CCC2(C)C ; CC(C)(C)c1ccc(N2B3c4oc5cc6c(cc5c4N(c4ccc(C(C)(C)C)cc4-c4ccccc4)c4cc5ccccc5c(c43)-c3ccc4sc5ccccc5c4c32)C(C)(C)CCC6(C)C)cc1] 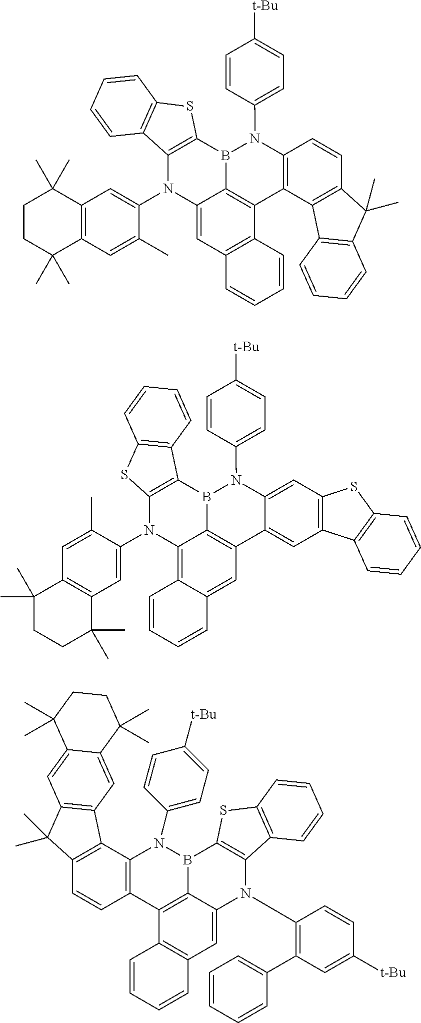 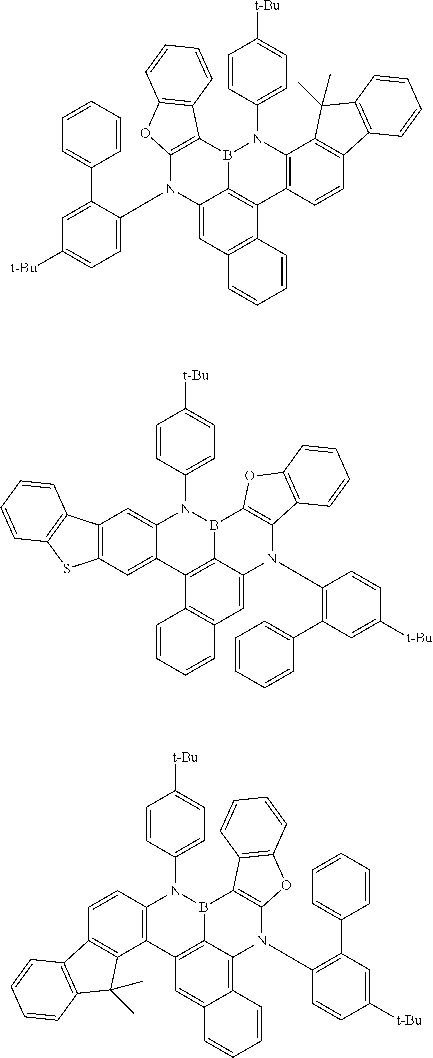 [SMILES: CC(C)(C)c1ccc(N2B3c4c(cc5ccccc5c4-c4ccc5c(c42)C(C)(C)c2ccccc2-5)N(c2ccc(C(C)(C)C)cc2-c2ccccc2)c2oc4ccccc4c23)cc1 ; CC(C)(C)c1ccc(N2B3c4oc5ccccc5c4N(c4ccc(C(C)(C)C)cc4-c4ccccc4)c4cc5ccccc5c(c43)-c3cc4sc5ccccc5c4cc32)cc1 ; CC(C)(C)c1ccc(N2B3c4c(cc5ccccc5c4N(c4ccc(C(C)(C)C)cc4-c4ccccc4)c4oc5ccccc5c43)-c3c2ccc2c3C(C)(C)c3ccccc3-2)cc1] 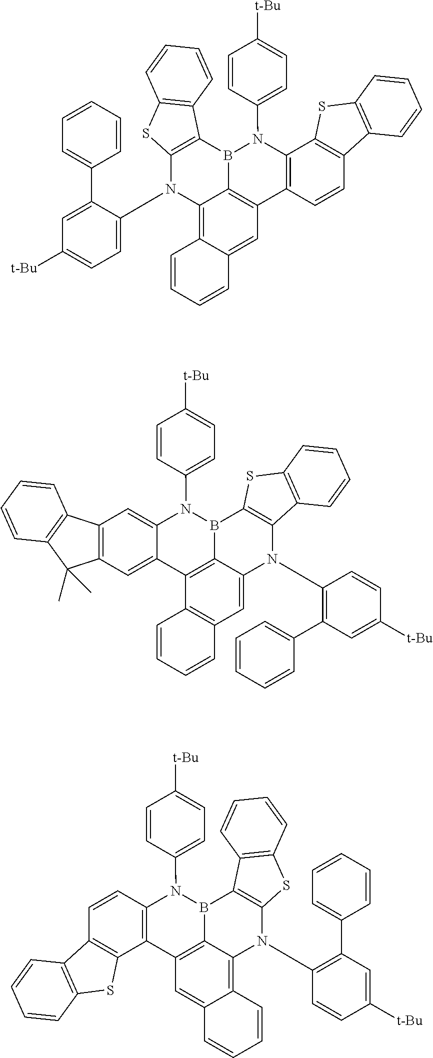 [SMILES: CC(C)(C)c1ccc(N2B3c4c(cc5ccccc5c4N(c4ccc(C(C)(C)C)cc4-c4ccccc4)c4sc5ccccc5c43)-c3ccc4c(sc5ccccc54)c32)cc1 ; CC(C)(C)c1ccc(N2B3c4sc5ccccc5c4N(c4ccc(C(C)(C)C)cc4-c4ccccc4)c4cc5ccccc5c(c43)-c3cc4c(cc32)-c2ccccc2C4(C)C)cc1 ; CC(C)(C)c1ccc(N2B3c4c(cc5ccccc5c4N(c4ccc(C(C)(C)C)cc4-c4ccccc4)c4sc5ccccc5c43)-c3c2ccc2c3sc3ccccc32)cc1] 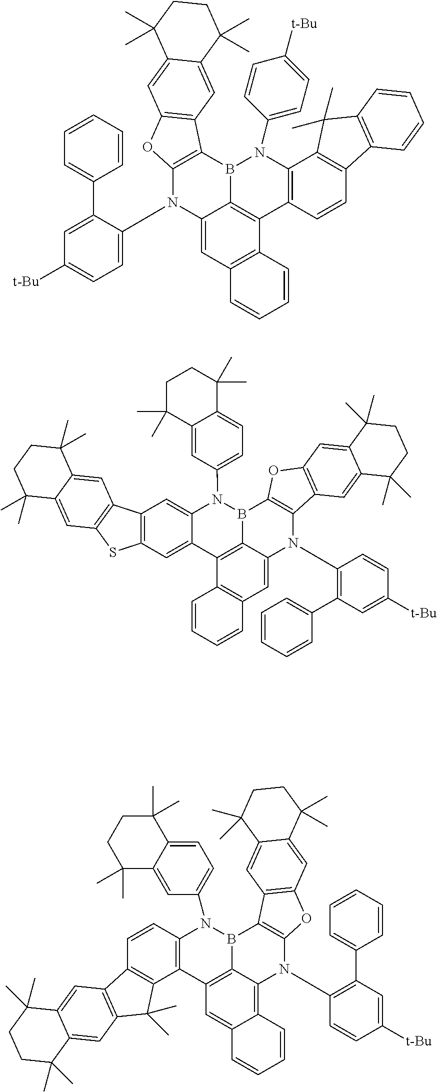 [SMILES: CC(C)(C)c1ccc(N2B3c4c(cc5ccccc5c4-c4ccc5c(c42)C(C)(C)c2ccccc2-5)N(c2ccc(C(C)(C)C)cc2-c2ccccc2)c2oc4cc5c(cc4c23)C(C)(C)CCC5(C)C)cc1 ; CC(C)(C)c1ccc(N2c3cc4ccccc4c4c3B(c3oc5cc6c(cc5c32)C(C)(C)CCC6(C)C)N(c2ccc3c(c2)C(C)(C)CCC3(C)C)c2cc3c(cc2-4)sc2cc4c(cc23)C(C)(C)CCC4(C)C)c(-c2ccccc2)c1 ; CC(C)(C)c1ccc(N2c3oc4cc5c(cc4c3B3c4c(cc6ccccc6c42)-c2c(ccc4c2C(C)(C)c2cc6c(cc2-4)C(C)(C)CCC6(C)C)N3c2ccc3c(c2)C(C)(C)CCC3(C)C)C(C)(C)CCC5(C)C)c(-c2ccccc2)c1] 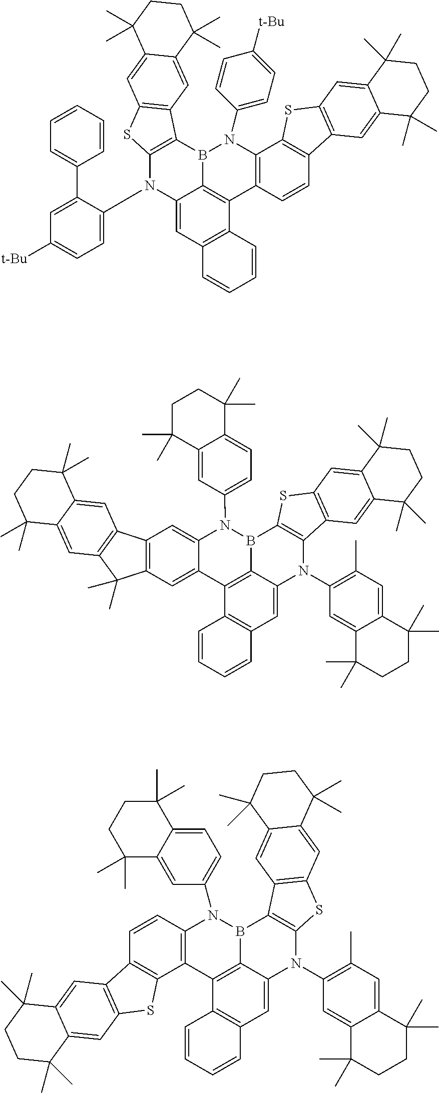 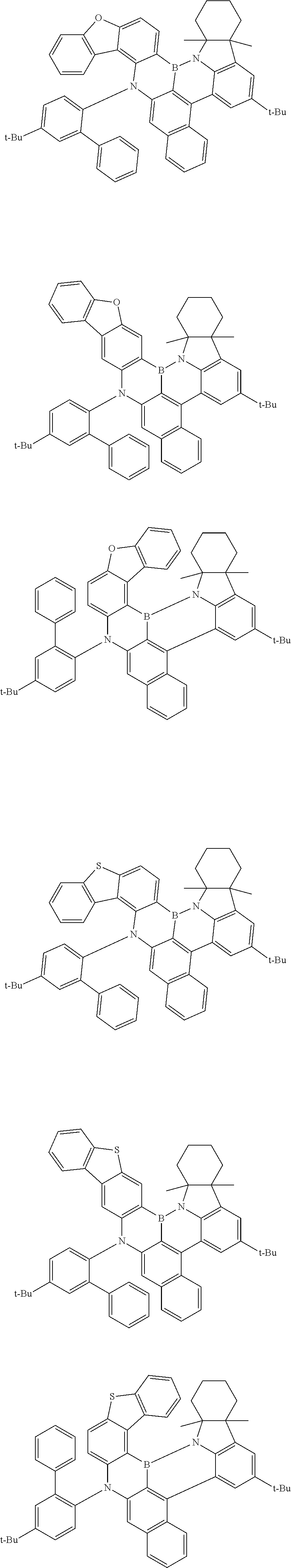 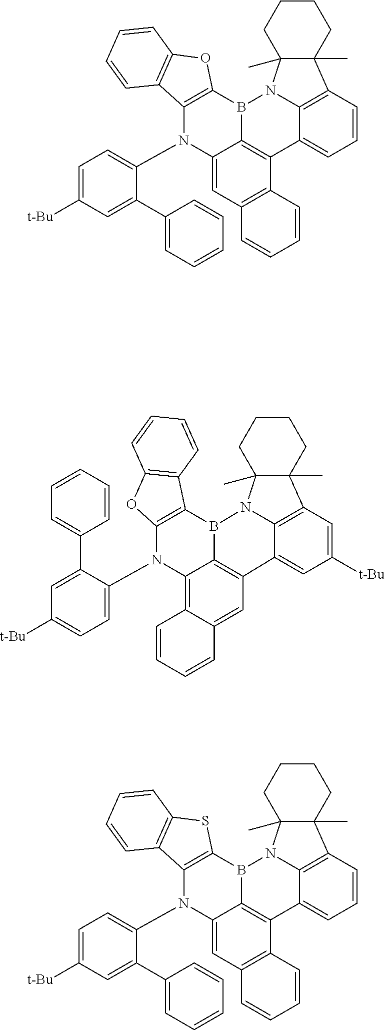 [SMILES: CC(C)(C)c1ccc(N2c3cc4ccccc4c4c3B(c3oc5ccccc5c32)N2c3c-4cccc3C3(C)CCCCC23C)c(-c2ccccc2)c1 ; CC(C)(C)c1ccc(N2c3oc4ccccc4c3B3c4c(cc5ccccc5c42)-c2cc(C(C)(C)C)cc4c2N3C2(C)CCCCC42C)c(-c2ccccc2)c1 ; CC(C)(C)c1ccc(N2c3cc4ccccc4c4c3B(c3sc5ccccc5c32)N2c3c-4cccc3C3(C)CCCCC23C)c(-c2ccccc2)c1] 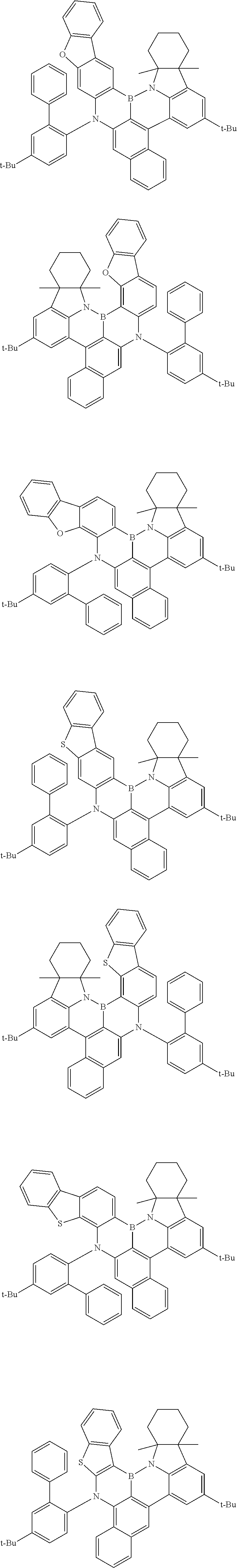 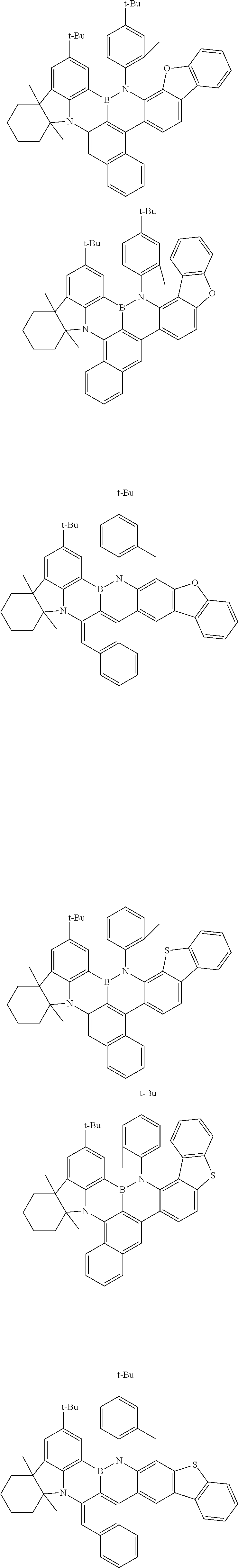 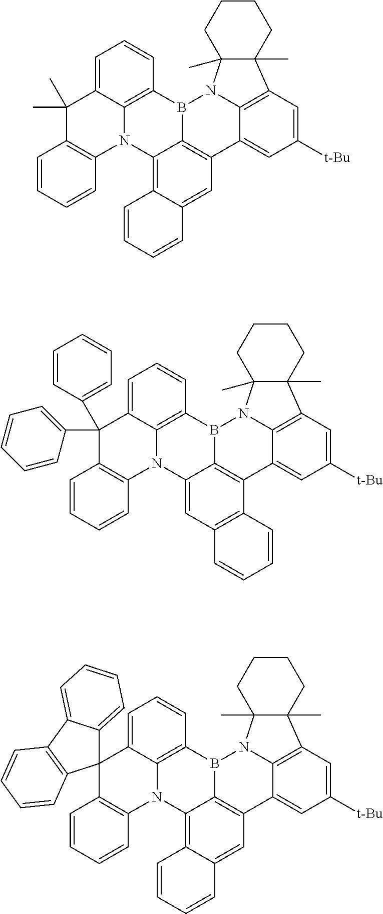 [SMILES: CC(C)(C)c1cc2c3c(c1)C1(C)CCCCC1(C)N3B1c3cccc4c3N(c3ccccc3C4(C)C)c3c1c-2cc1ccccc31 ; CC(C)(C)c1cc2c3c(c1)C1(C)CCCCC1(C)N3B1c3cccc4c3N(c3ccccc3C4(c3ccccc3)c3ccccc3)c3cc4ccccc4c-2c31 ; CC(C)(C)c1cc2c3c(c1)C1(C)CCCCC1(C)N3B1c3cccc4c3N(c3ccccc3C43c4ccccc4-c4ccccc43)c3c1c-2cc1ccccc31] 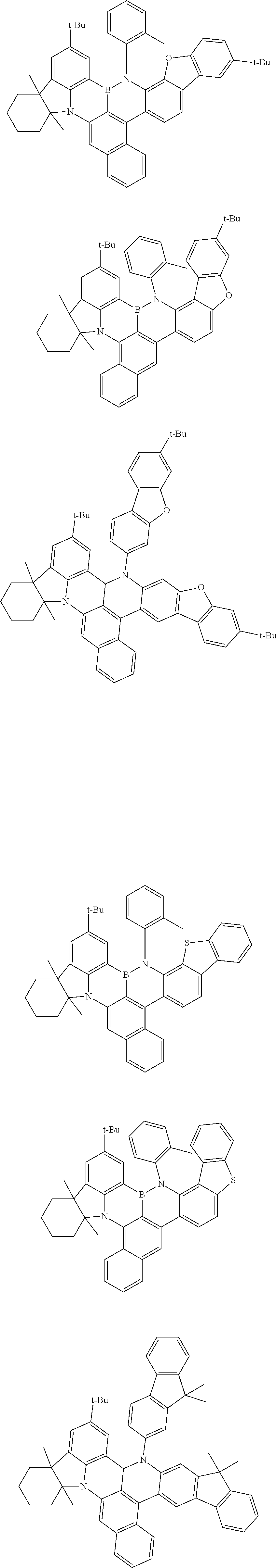 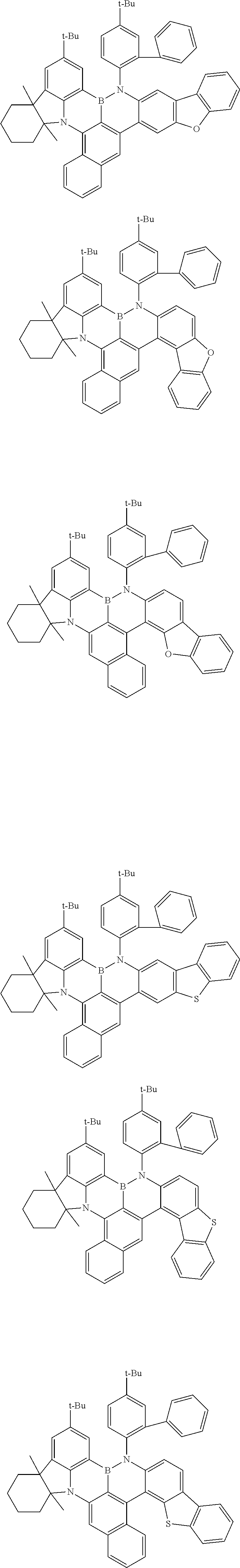 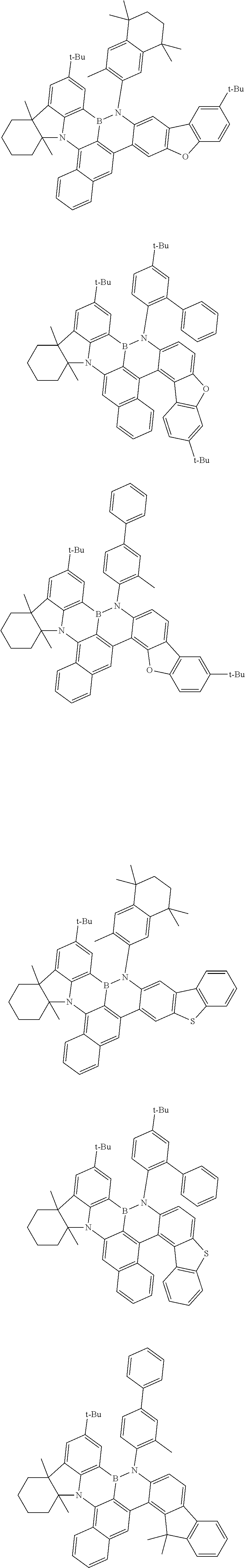 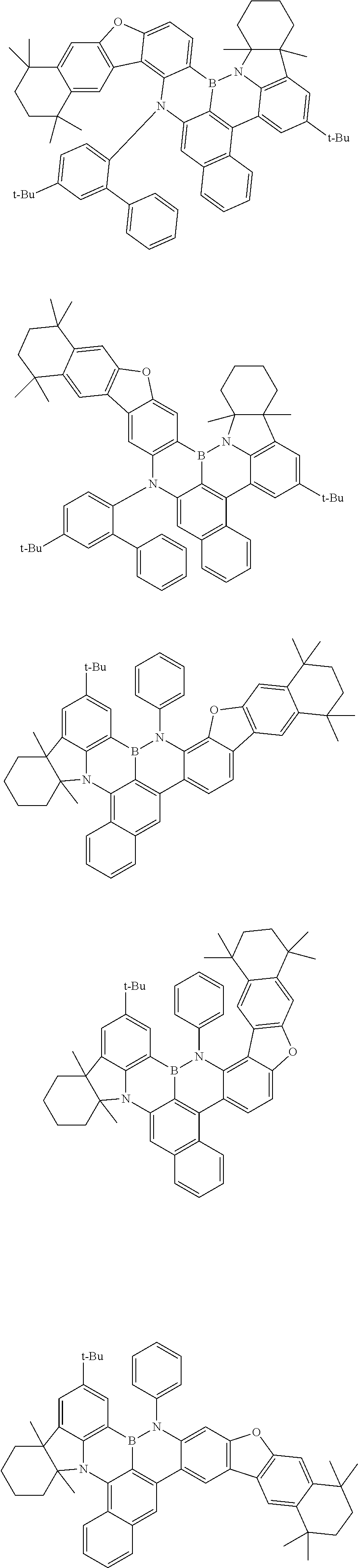 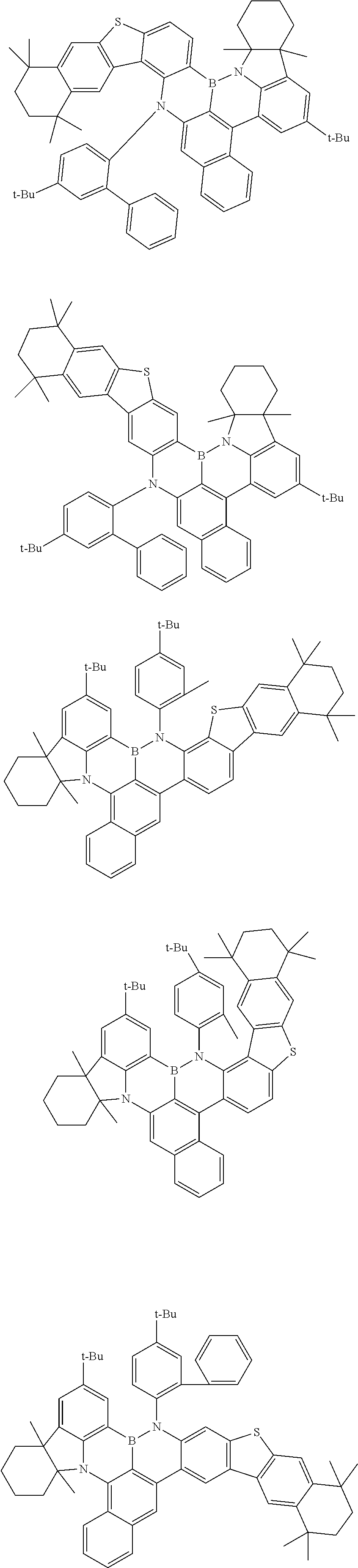 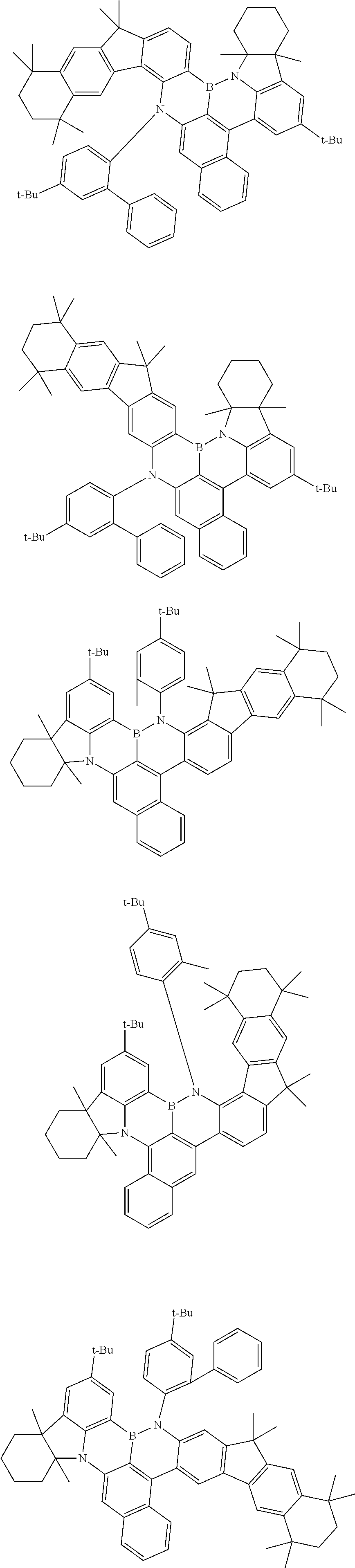 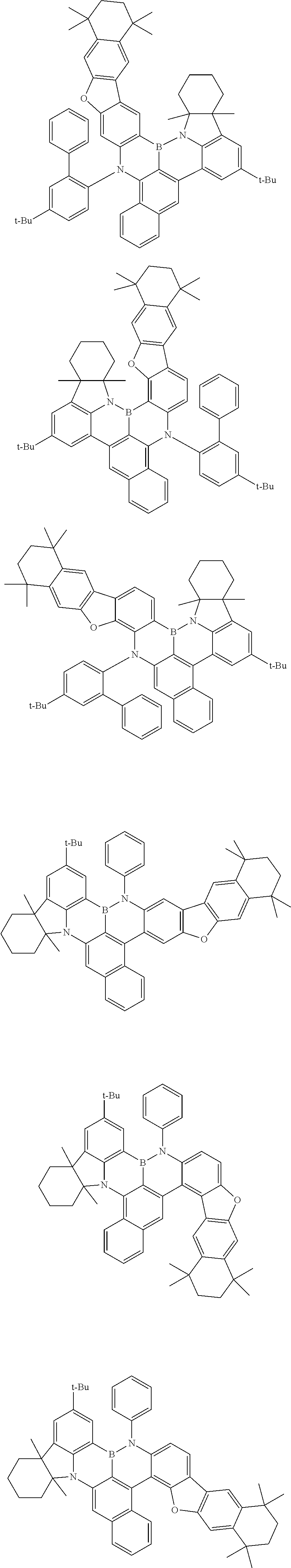 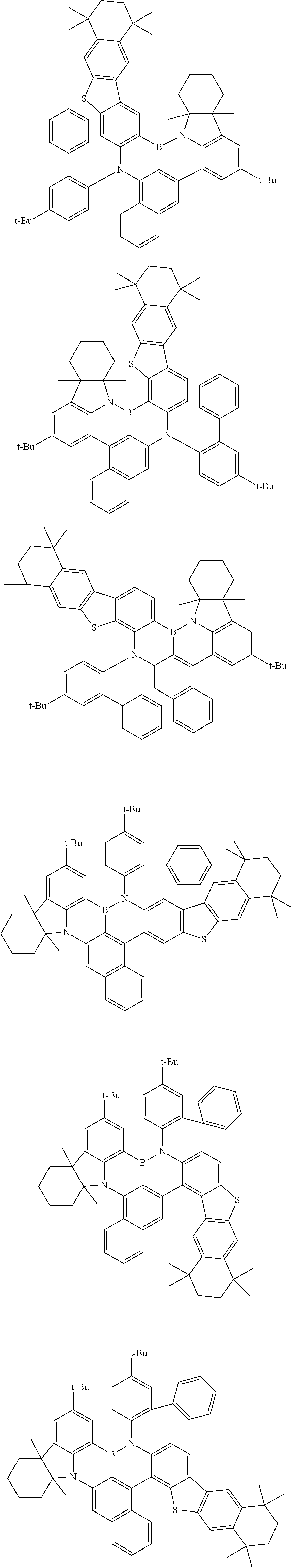 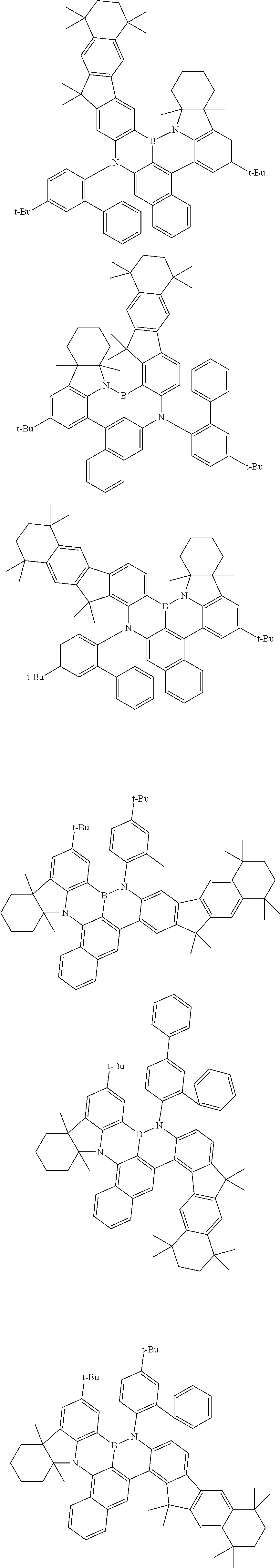 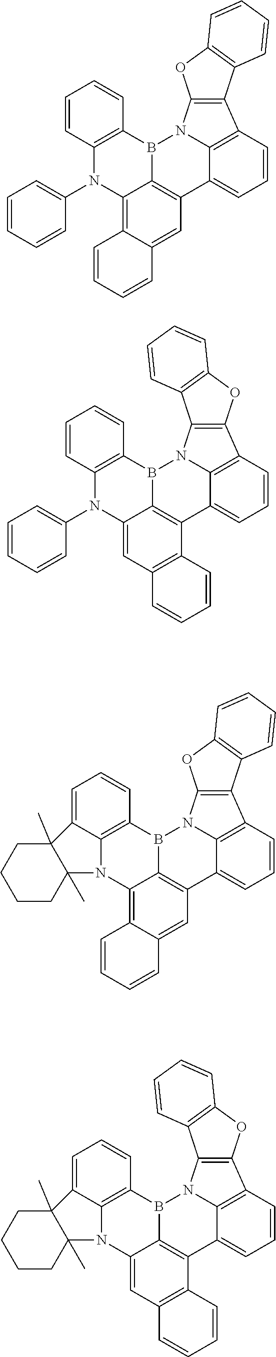 [SMILES: c1ccc(N2c3ccccc3B3c4c(cc5ccccc5c42)-c2cccc4c5c6ccccc6oc5n3c24)cc1 ; c1ccc(N2c3ccccc3B3c4c2cc2ccccc2c4-c2cccc4c5oc6ccccc6c5n3c24)cc1 ; CC12CCCCC1(C)N1c3c(cccc32)B2c3c(cc4ccccc4c31)-c1cccc3c4c5ccccc5oc4n2c13 ; CC12CCCCC1(C)N1c3cc4ccccc4c4c3B(c3cccc2c31)n1c2c-4cccc2c2oc3ccccc3c21] 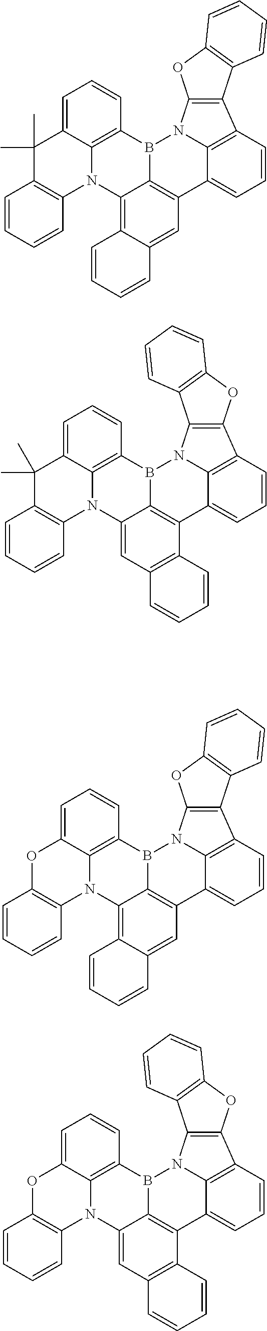 [SMILES: CC1(C)c2ccccc2N2c3c(cccc31)B1c3c(cc4ccccc4c32)-c2cccc3c4c5ccccc5oc4n1c23 ; CC1(C)c2ccccc2N2c3cc4ccccc4c4c3B(c3cccc1c32)n1c2c-4cccc2c2oc3ccccc3c21 ; c1ccc2c(c1)Oc1cccc3c1N2c1c2c(cc4ccccc14)-c1cccc4c5c6ccccc6oc5n(c14)B32 ; c1ccc2c(c1)Oc1cccc3c1N2c1cc2ccccc2c2c1B3n1c3c-2cccc3c2oc3ccccc3c21] 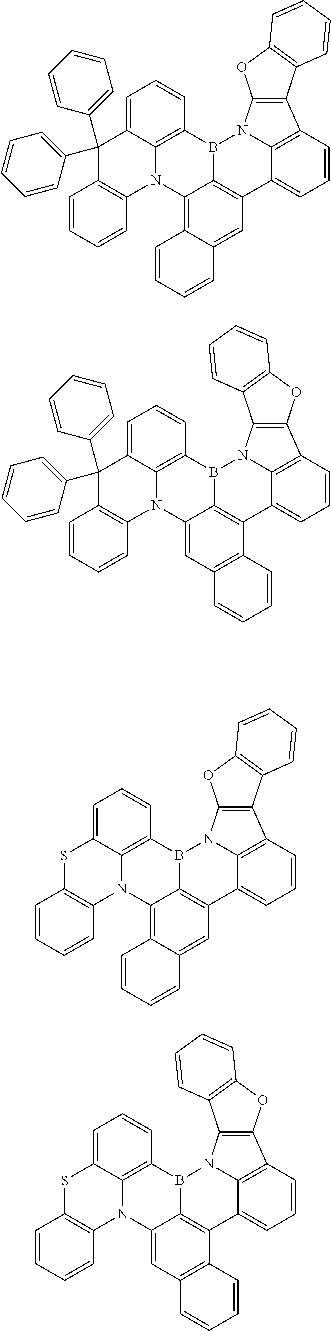 [SMILES: c1ccc(C2(c3ccccc3)c3ccccc3N3c4c(cccc42)B2c4c(cc5ccccc5c43)-c3cccc4c5c6ccccc6oc5n2c34)cc1 ; c1ccc(C2(c3ccccc3)c3ccccc3N3c4cc5ccccc5c5c4B(c4cccc2c43)n2c3c-5cccc3c3oc4ccccc4c32)cc1 ; c1ccc2c(c1)Sc1cccc3c1N2c1c2c(cc4ccccc14)-c1cccc4c5c6ccccc6oc5n(c14)B32 ; c1ccc2c(c1)Sc1cccc3c1N2c1cc2ccccc2c2c1B3n1c3c-2cccc3c2oc3ccccc3c21] 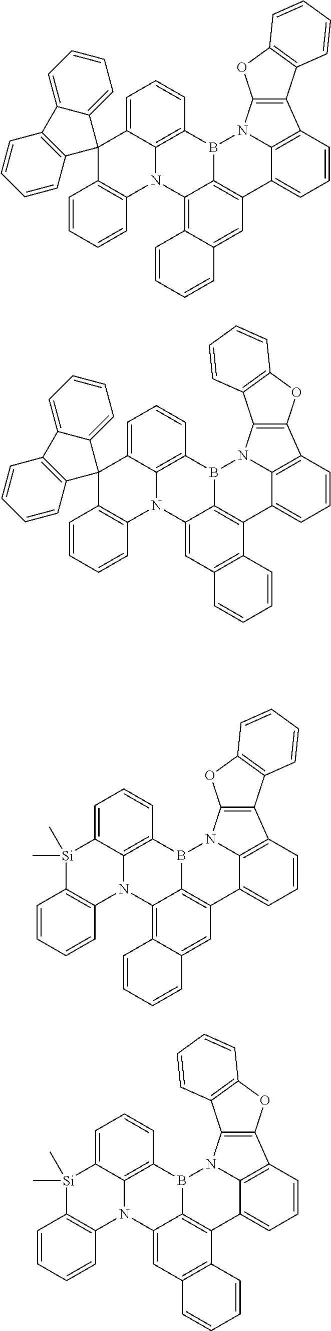 [SMILES: c1ccc2c(c1)-c1ccccc1C21c2ccccc2N2c3c(cccc31)B1c3c(cc4ccccc4c32)-c2cccc3c4c5ccccc5oc4n1c23 ; c1ccc2c(c1)-c1ccccc1C21c2ccccc2N2c3cc4ccccc4c4c3B(c3cccc1c32)n1c2c-4cccc2c2oc3ccccc3c21 ; C[Si]1(C)c2ccccc2N2c3c(cccc31)B1c3c(cc4ccccc4c32)-c2cccc3c4c5ccccc5oc4n1c23 ; C[Si]1(C)c2ccccc2N2c3cc4ccccc4c4c3B(c3cccc1c32)n1c2c-4cccc2c2oc3ccccc3c21] 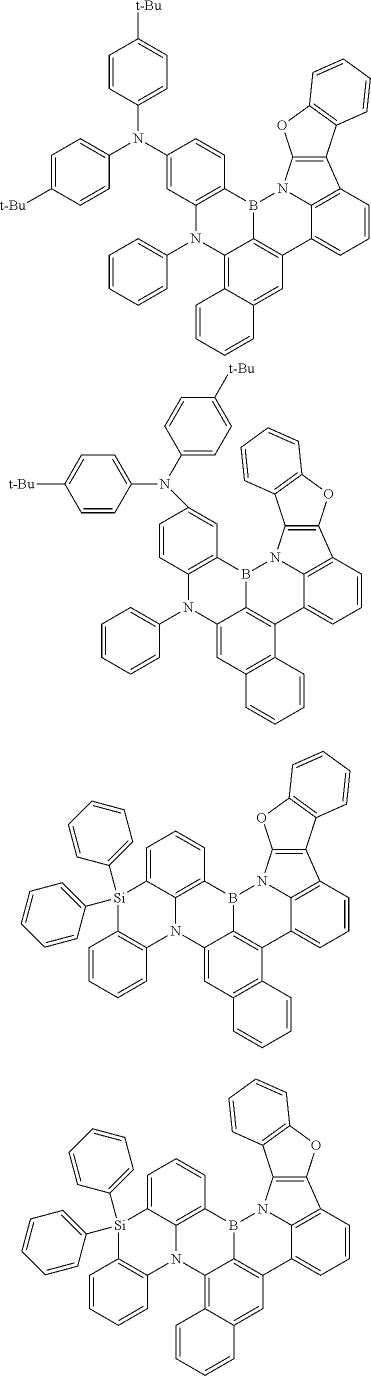 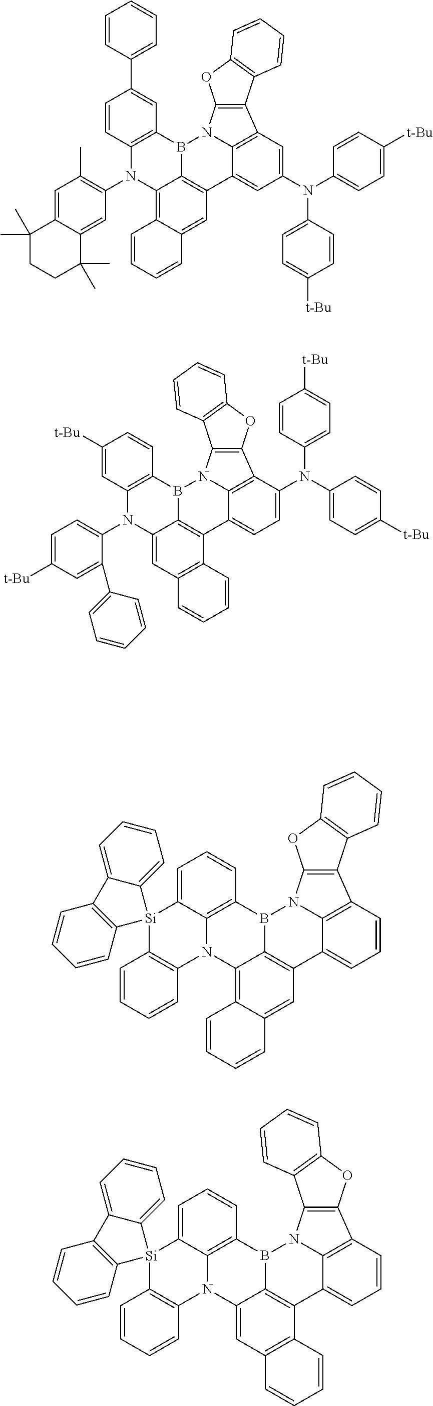 [SMILES: Cc1cc2c(cc1N1c3ccc(-c4ccccc4)cc3B3c4c(cc5ccccc5c41)-c1cc(N(c4ccc(C(C)(C)C)cc4)c4ccc(C(C)(C)C)cc4)cc4c5c6ccccc6oc5n3c14)C(C)(C)CCC2(C)C ; CC(C)(C)c1ccc(N(c2ccc(C(C)(C)C)cc2)c2ccc3c4c2c2oc5ccccc5c2n4B2c4ccc(C(C)(C)C)cc4N(c4ccc(C(C)(C)C)cc4-c4ccccc4)c4cc5ccccc5c-3c42)cc1 ; c1ccc2c(c1)-c1ccccc1[Si]21c2ccccc2N2c3c(cccc31)B1c3c(cc4ccccc4c32)-c2cccc3c4c5ccccc5oc4n1c23 ; c1ccc2c(c1)-c1ccccc1[Si]21c2ccccc2N2c3cc4ccccc4c4c3B(c3cccc1c32)n1c2c-4cccc2c2oc3ccccc3c21] 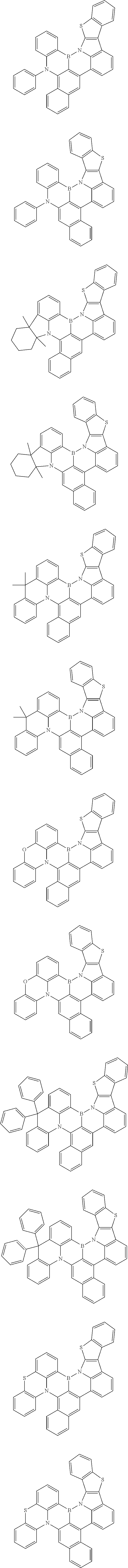 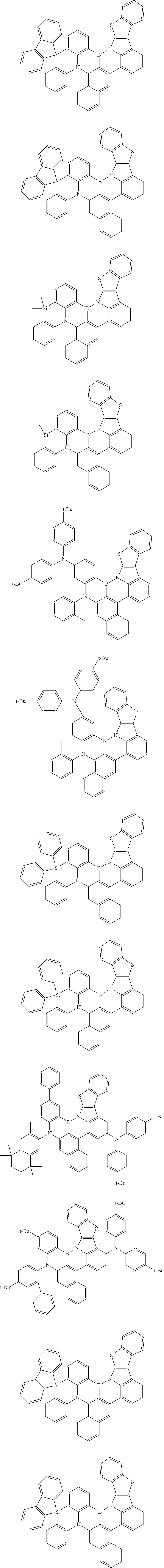 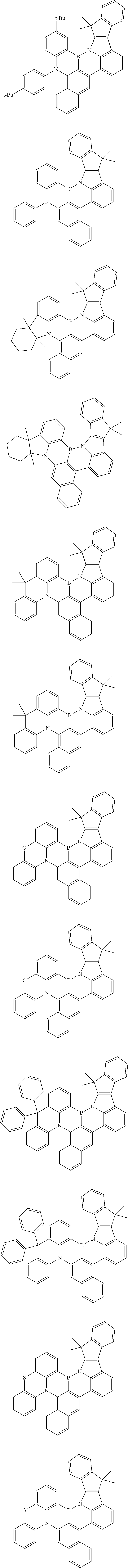 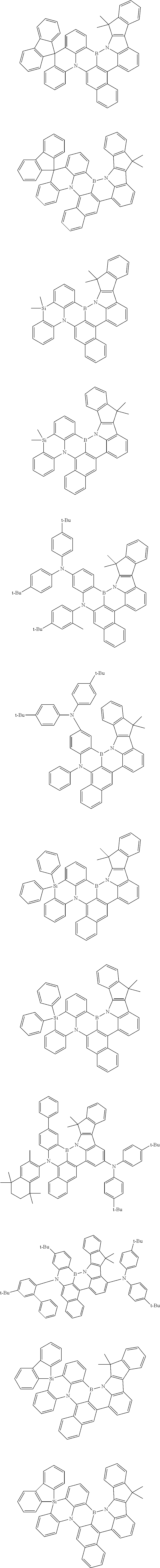 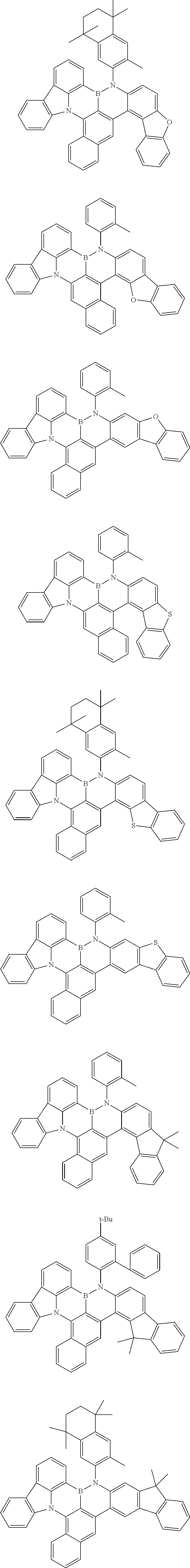 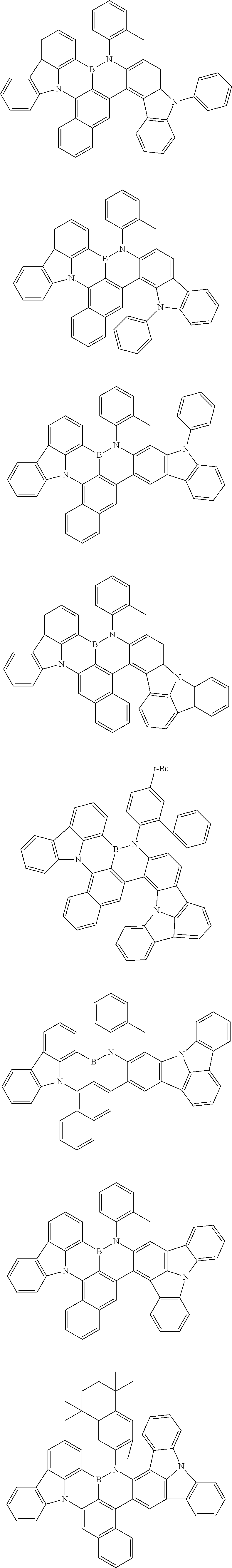 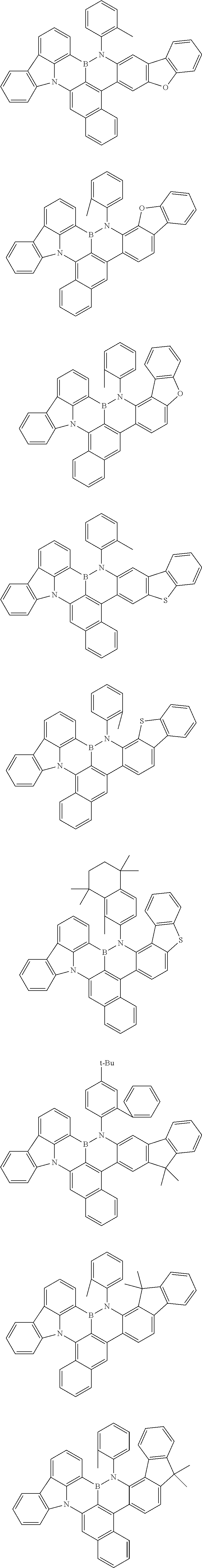 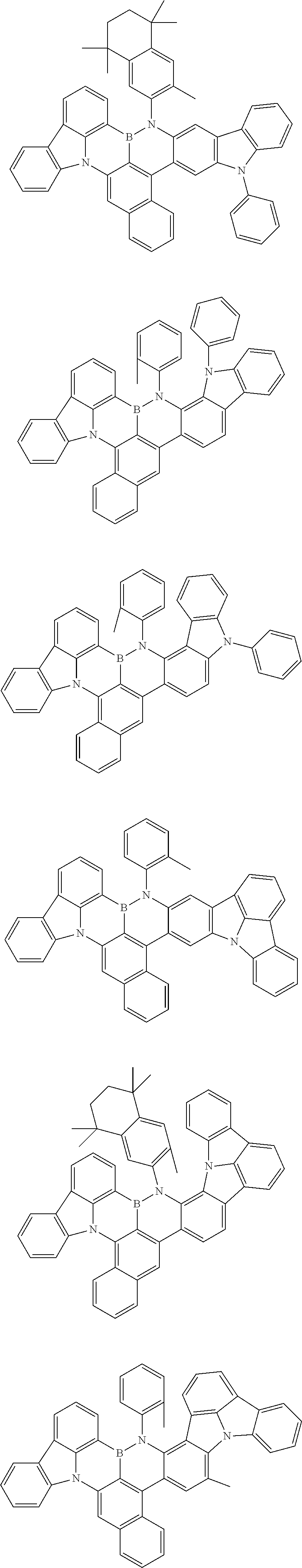 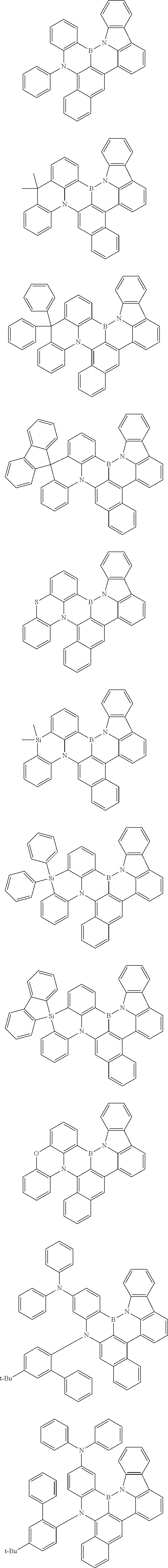 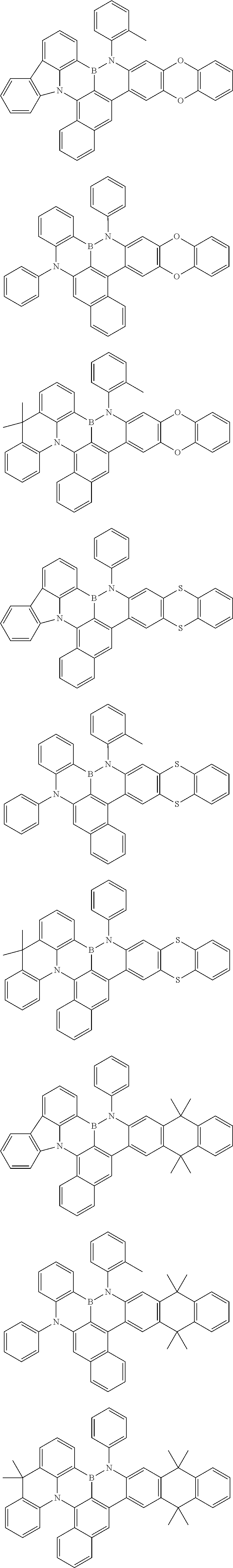 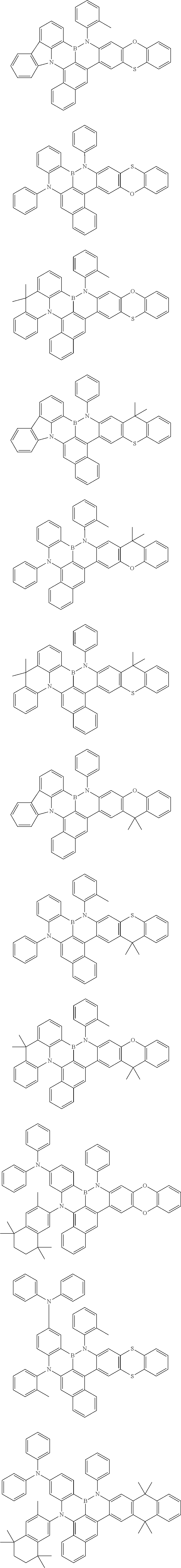 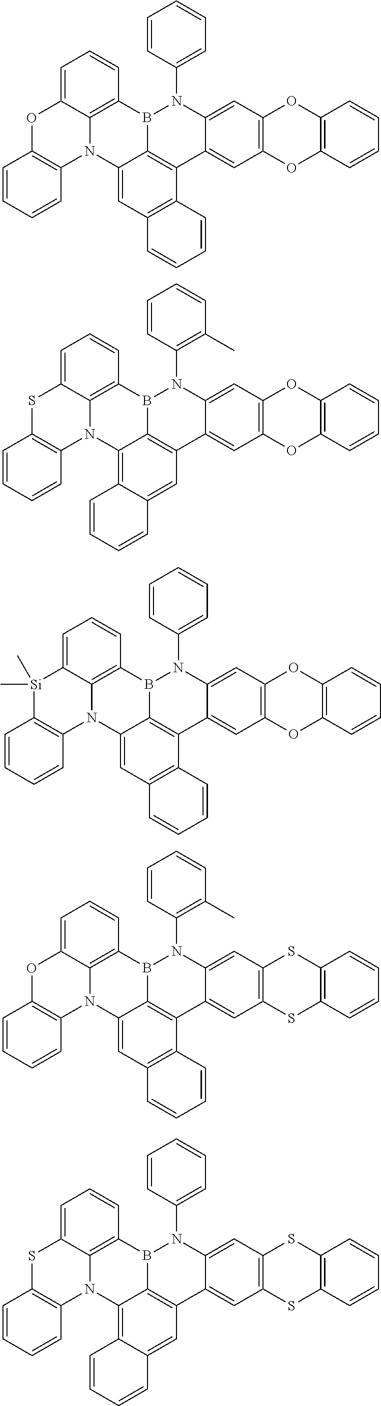 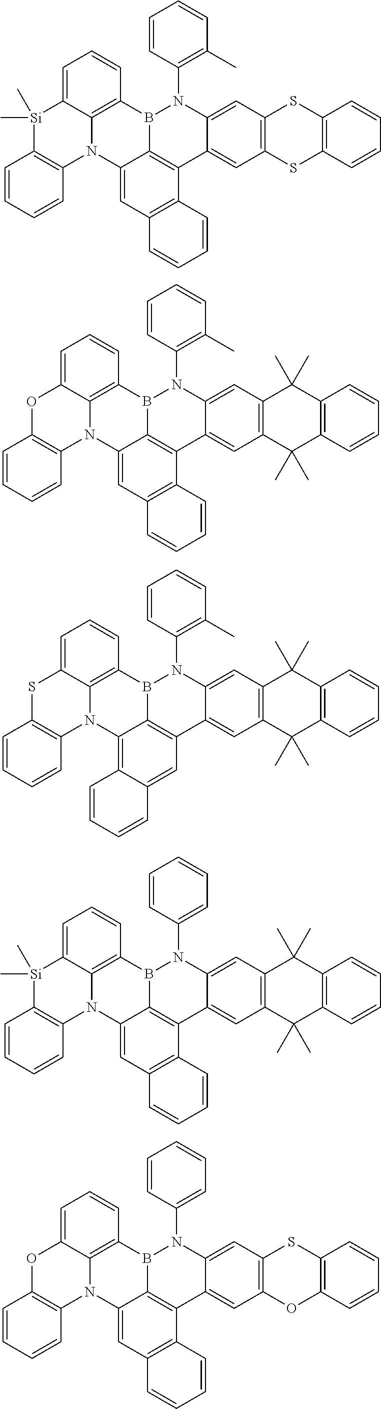 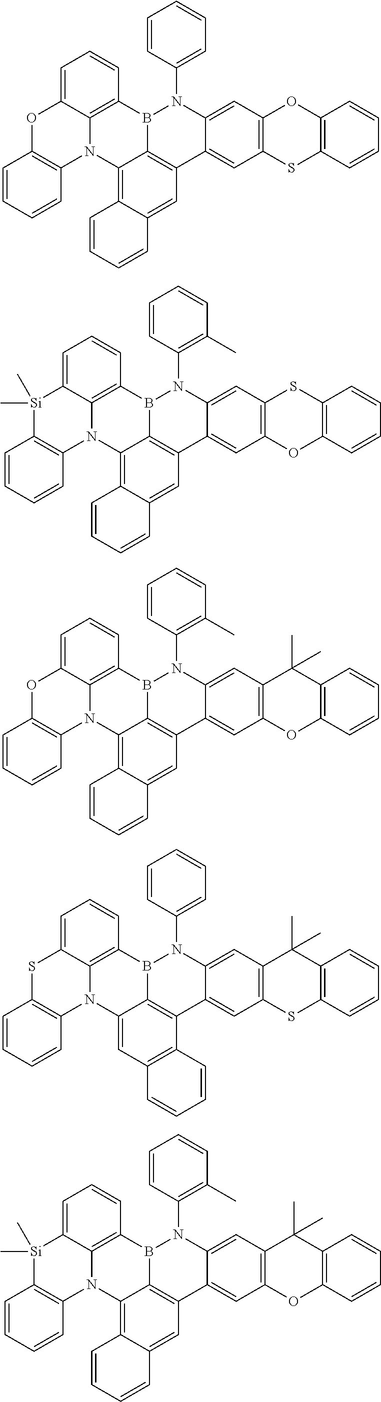 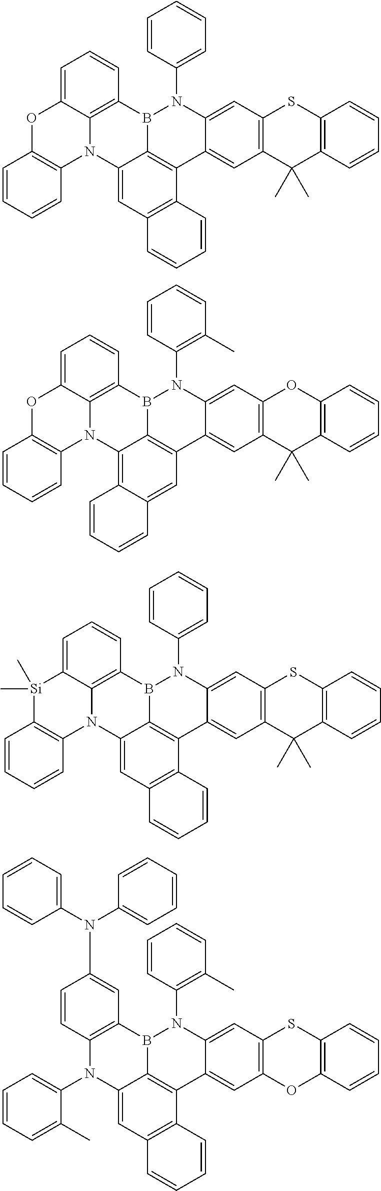 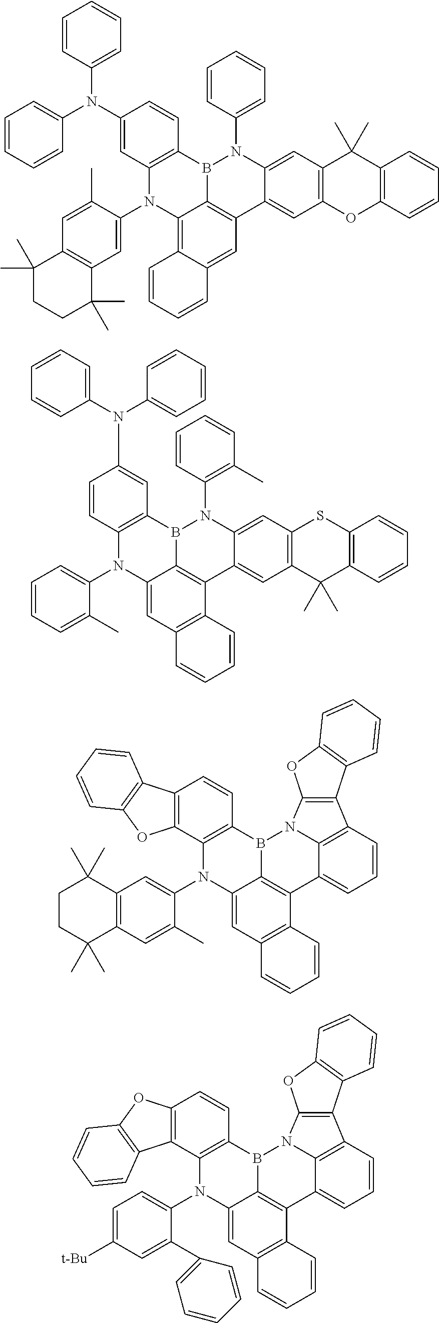 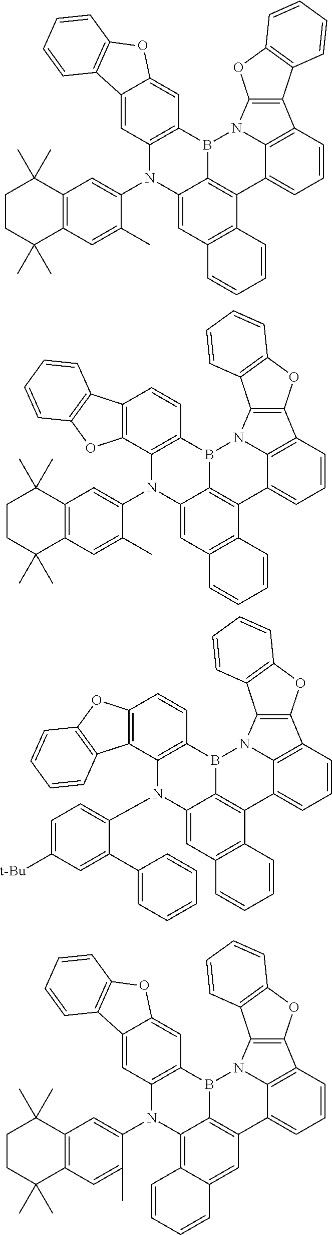 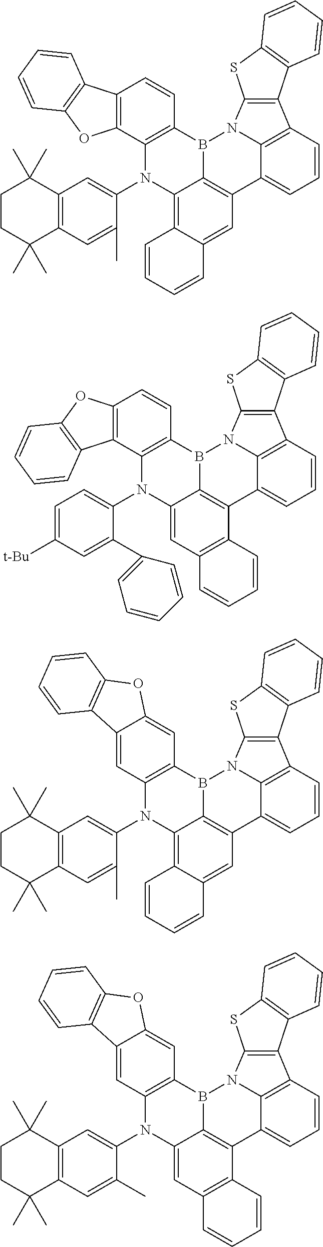 [SMILES: Cc1cc2c(cc1N1c3c4c(cc5ccccc35)-c3cccc5c6c7ccccc7sc6n(c35)B4c3ccc4c(oc5ccccc54)c31)C(C)(C)CCC2(C)C ; CC(C)(C)c1ccc(N2c3cc4ccccc4c4c3B(c3ccc5oc6ccccc6c5c32)n2c3sc5ccccc5c3c3cccc-4c32)c(-c2ccccc2)c1 ; Cc1cc2c(cc1N1c3cc4c(cc3B3c5c(cc6ccccc6c51)-c1cccc5c6c7ccccc7sc6n3c15)oc1ccccc14)C(C)(C)CCC2(C)C ; Cc1cc2c(cc1N1c3cc4c(cc3B3c5c1cc1ccccc1c5-c1cccc5c6c7ccccc7sc6n3c15)oc1ccccc14)C(C)(C)CCC2(C)C] 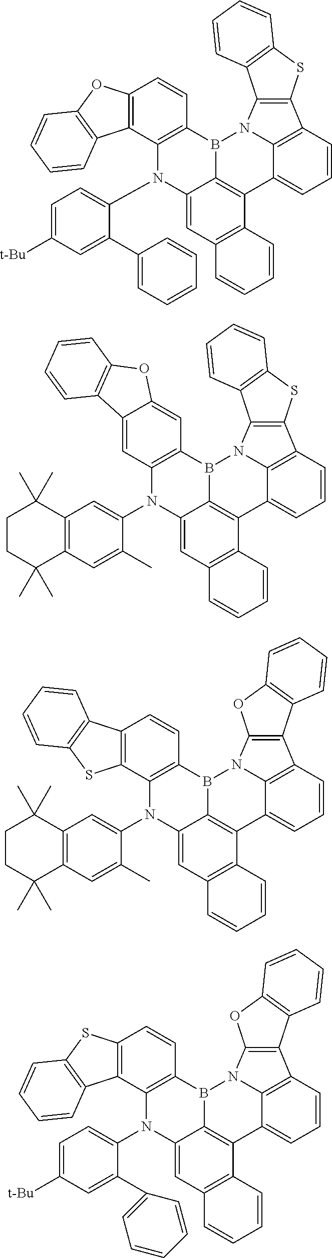 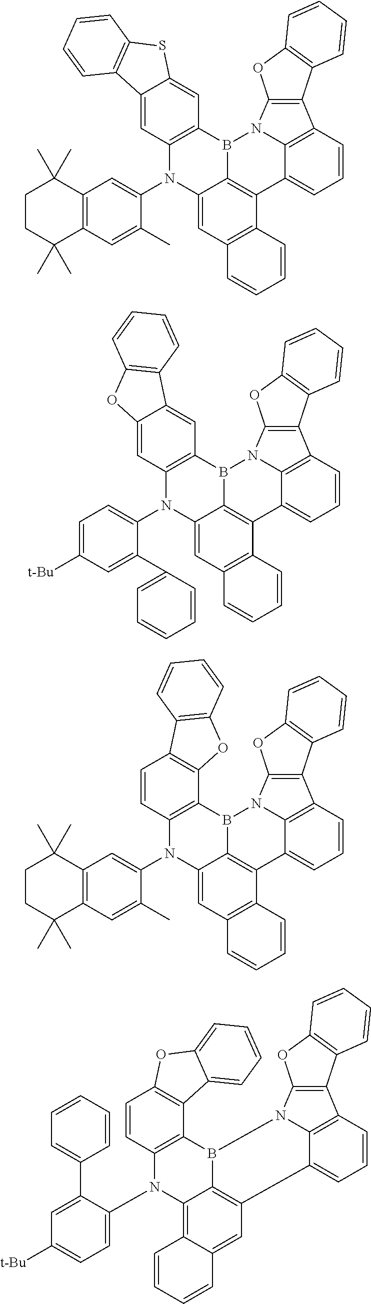 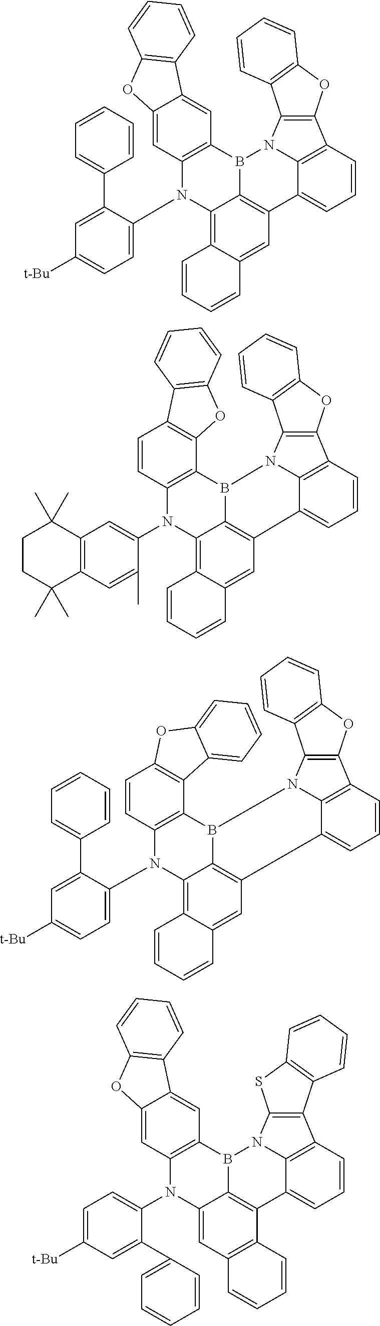 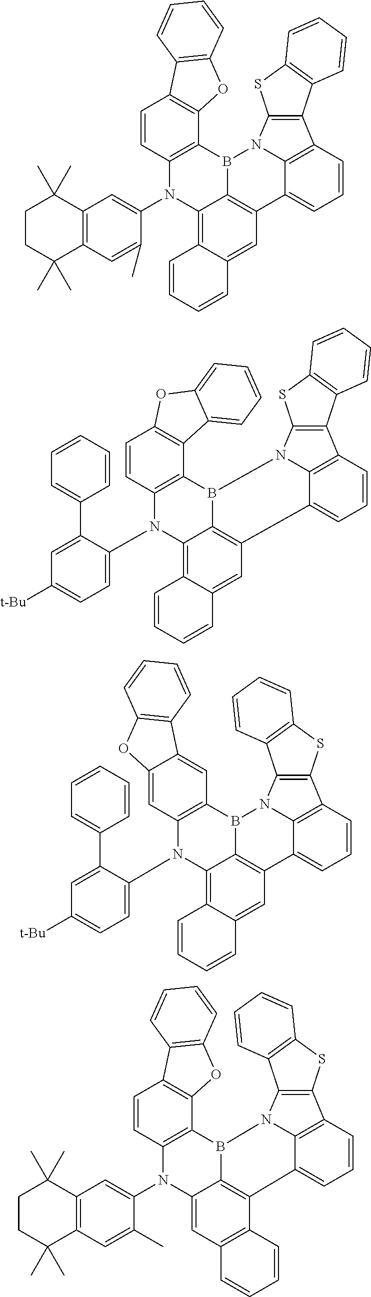 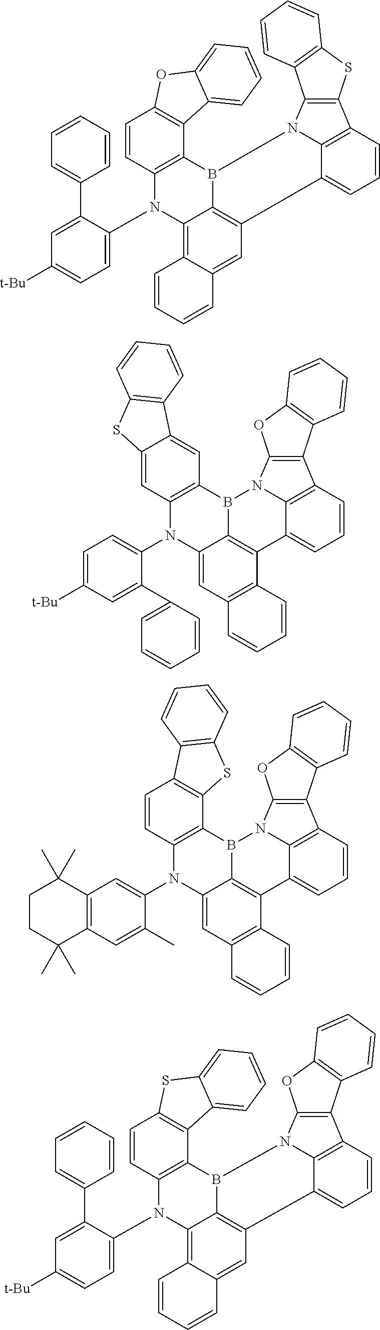 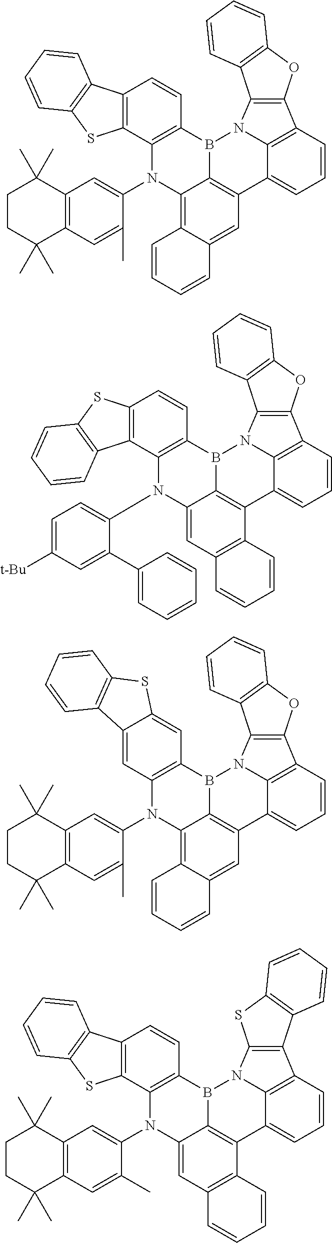 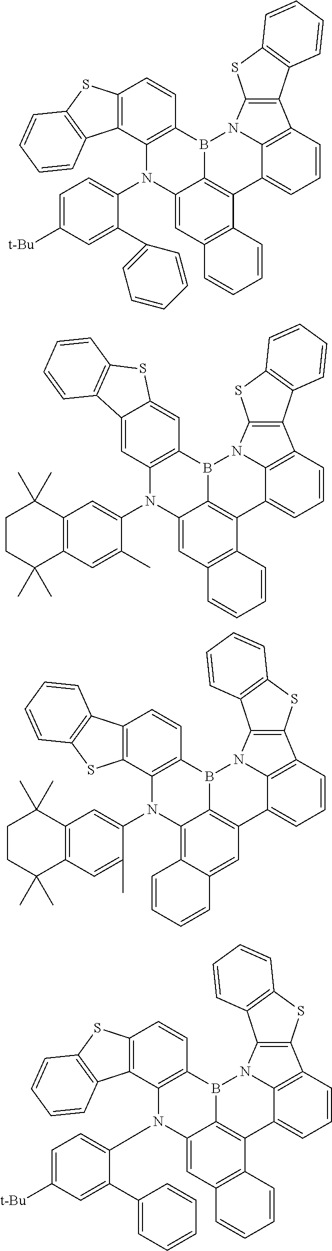 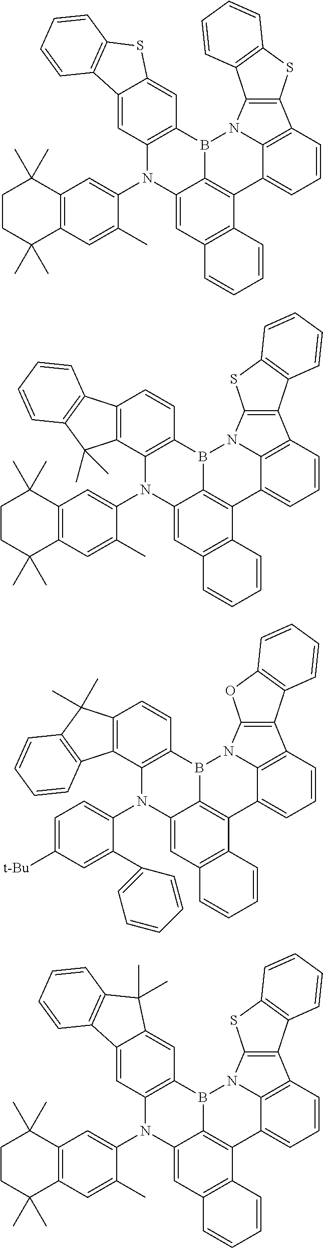 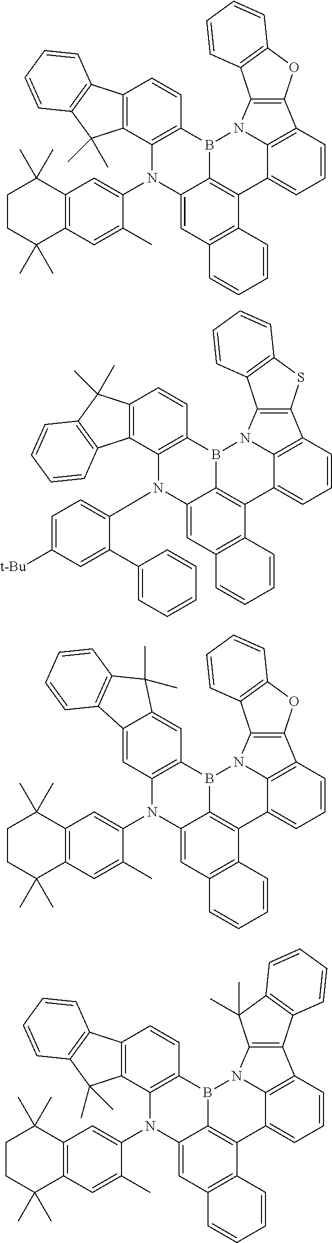 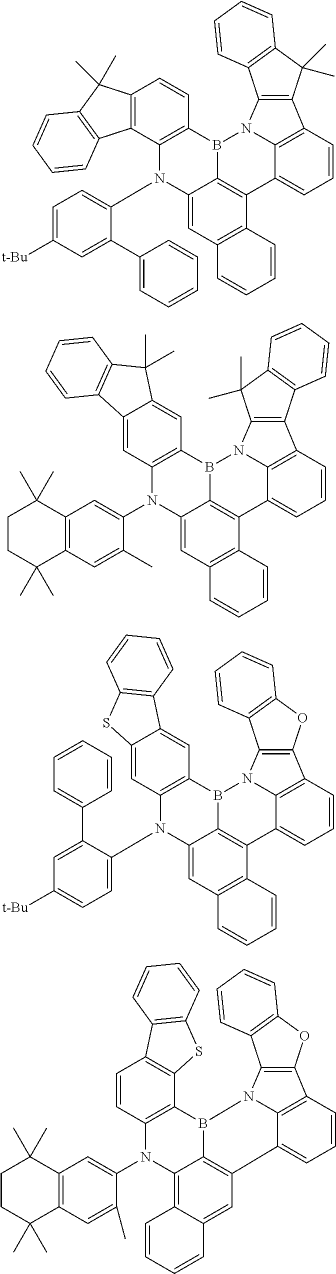 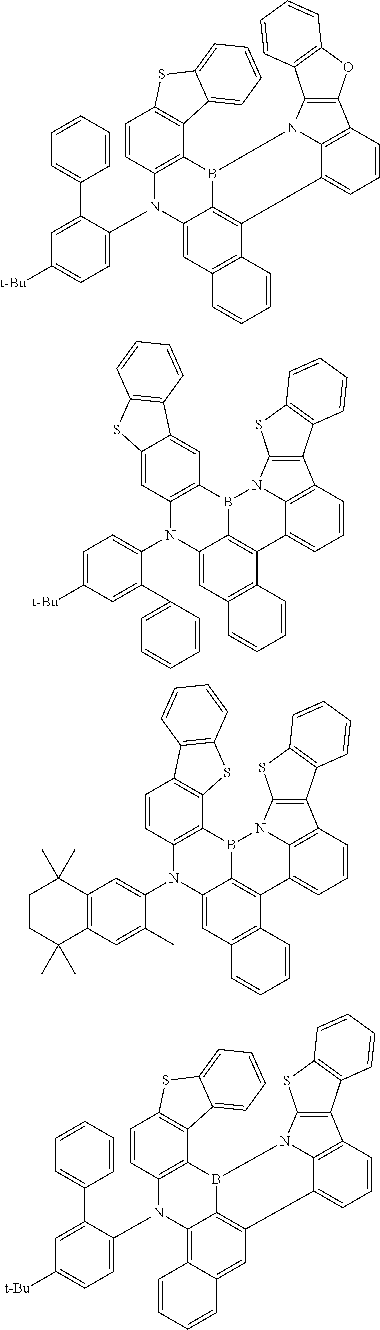 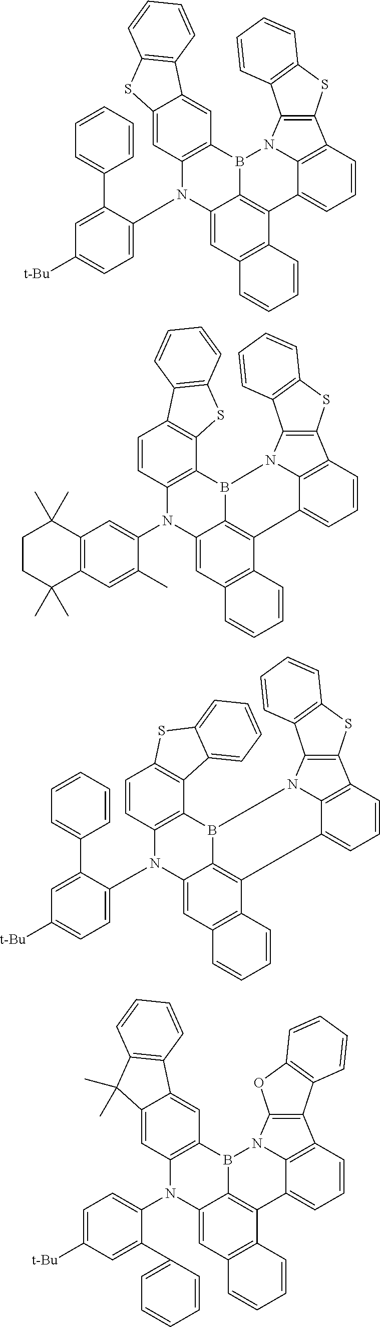 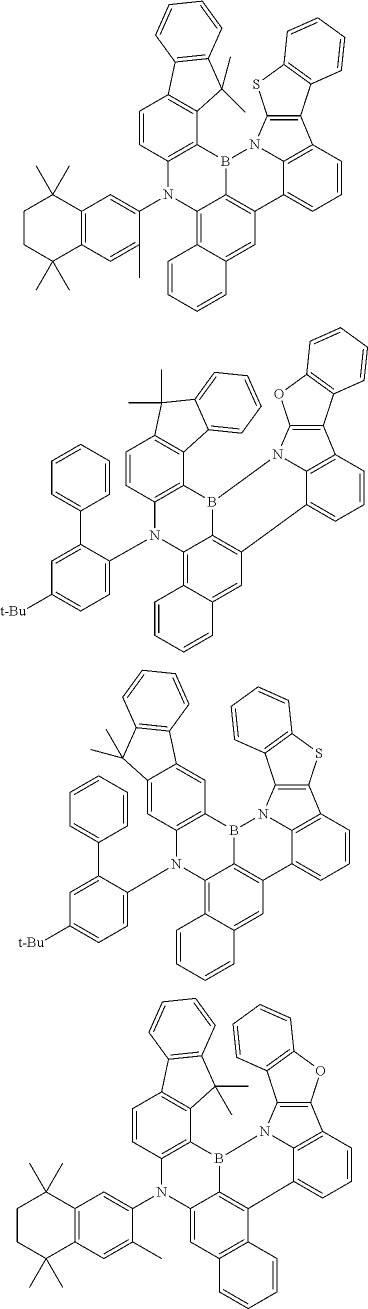 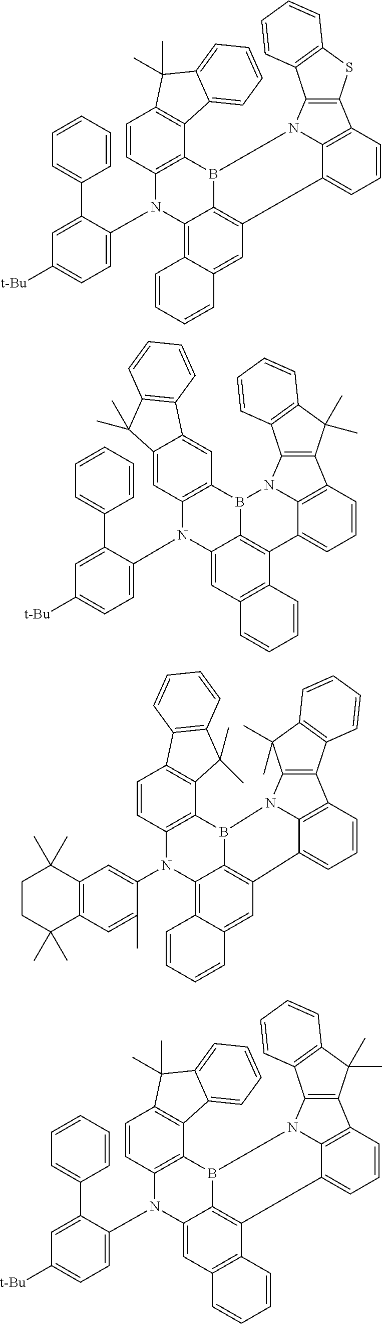 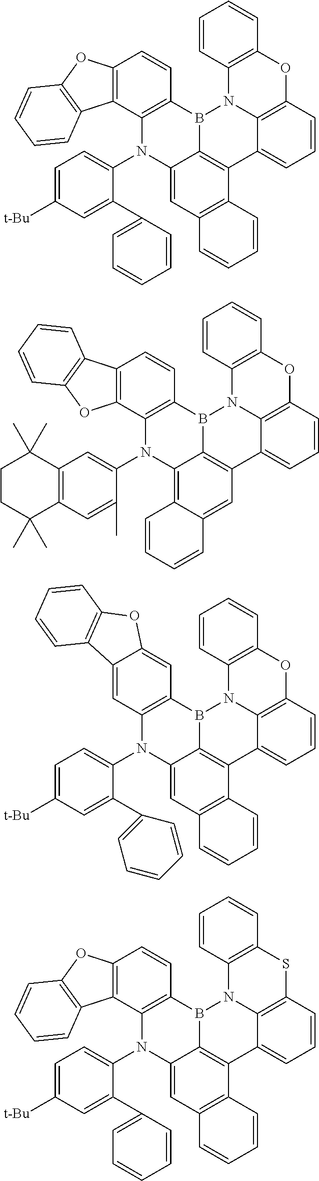 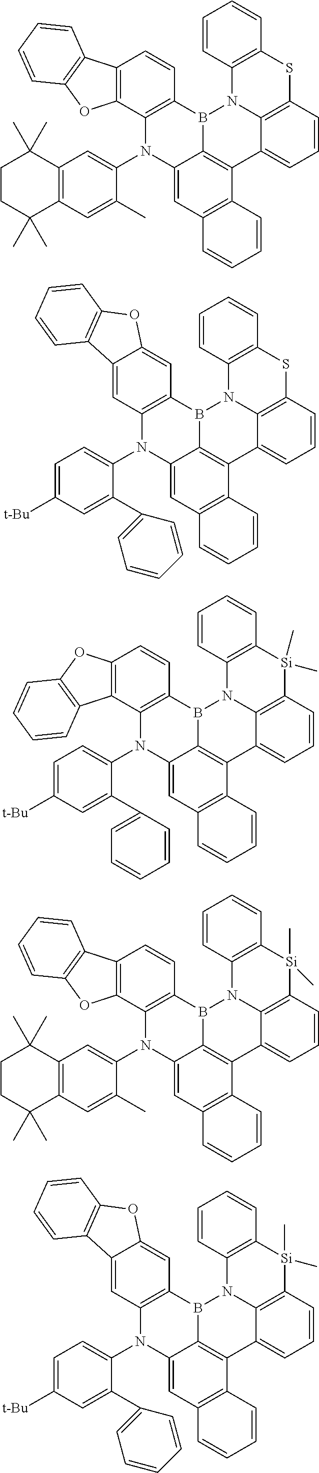 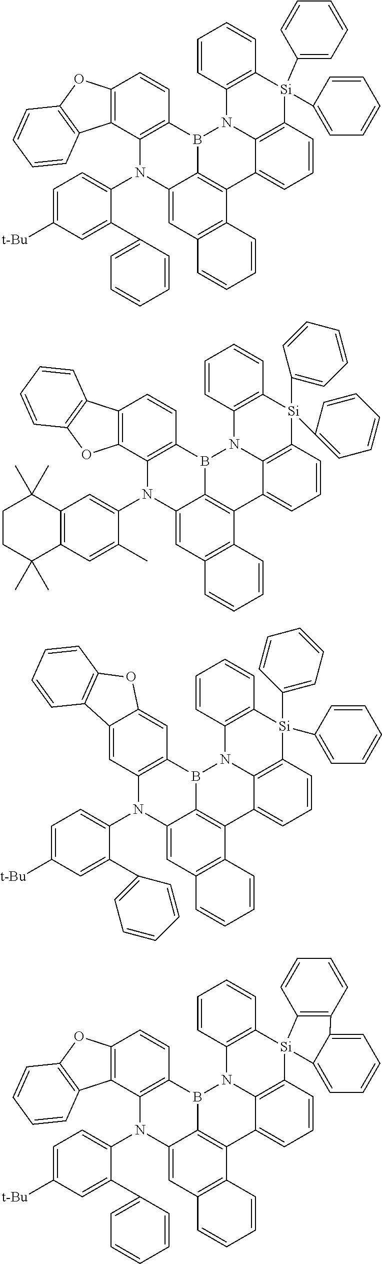 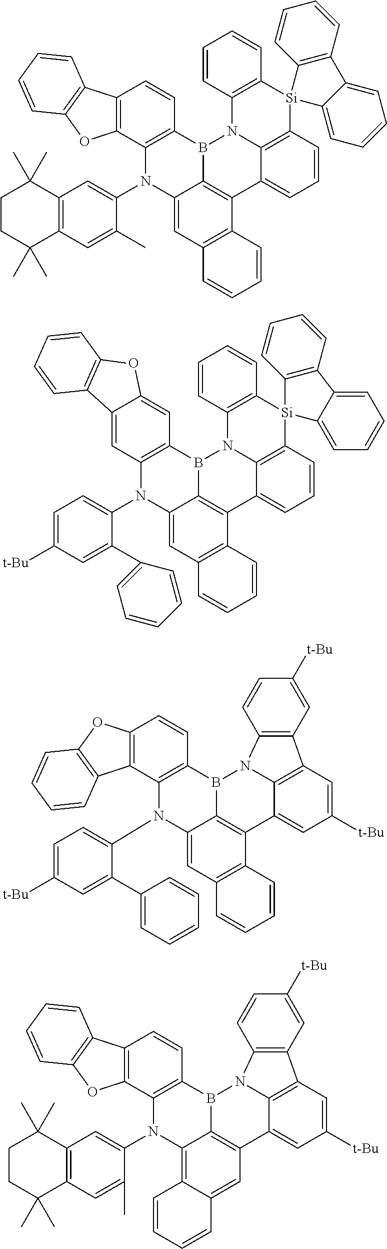 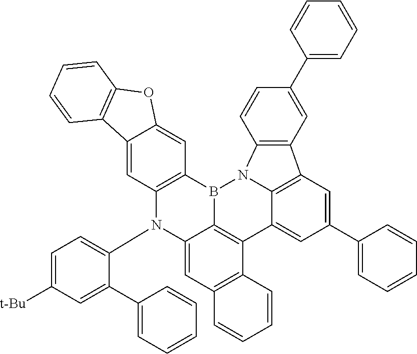 [SMILES: CC(C)(C)c1ccc(N2c3cc4c(cc3B3c5c2cc2ccccc2c5-c2cc(-c5ccccc5)cc5c6cc(-c7ccccc7)ccc6n3c25)oc2ccccc24)c(-c2ccccc2)c1] 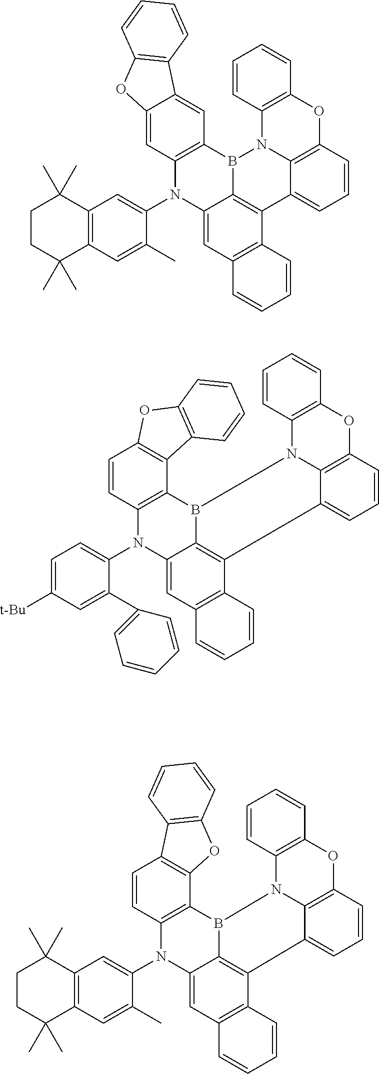 [SMILES: Cc1cc2c(cc1N1c3cc4oc5ccccc5c4cc3B3c4c1cc1ccccc1c4-c1cccc4c1N3c1ccccc1O4)C(C)(C)CCC2(C)C ; CC(C)(C)c1ccc(N2c3cc4ccccc4c4c3B(c3c2ccc2oc5ccccc5c32)N2c3ccccc3Oc3cccc-4c32)c(-c2ccccc2)c1 ; Cc1cc2c(cc1N1c3cc4ccccc4c4c3B(c3c1ccc1c3oc3ccccc31)N1c3ccccc3Oc3cccc-4c31)C(C)(C)CCC2(C)C] 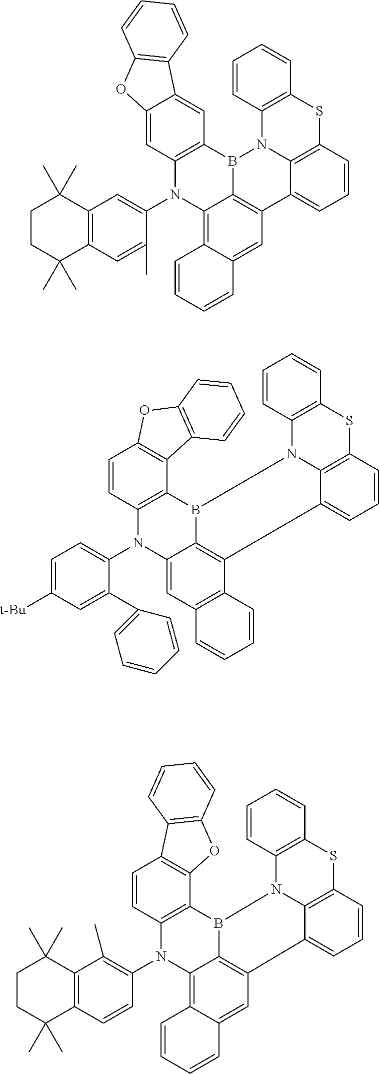 [SMILES: Cc1cc2c(cc1N1c3cc4oc5ccccc5c4cc3B3c4c(cc5ccccc5c41)-c1cccc4c1N3c1ccccc1S4)C(C)(C)CCC2(C)C ; CC(C)(C)c1ccc(N2c3cc4ccccc4c4c3B(c3c2ccc2oc5ccccc5c32)N2c3ccccc3Sc3cccc-4c32)c(-c2ccccc2)c1 ; Cc1c(N2c3ccc4c(oc5ccccc54)c3B3c4c(cc5ccccc5c42)-c2cccc4c2N3c2ccccc2S4)ccc2c1C(C)(C)CCC2(C)C] 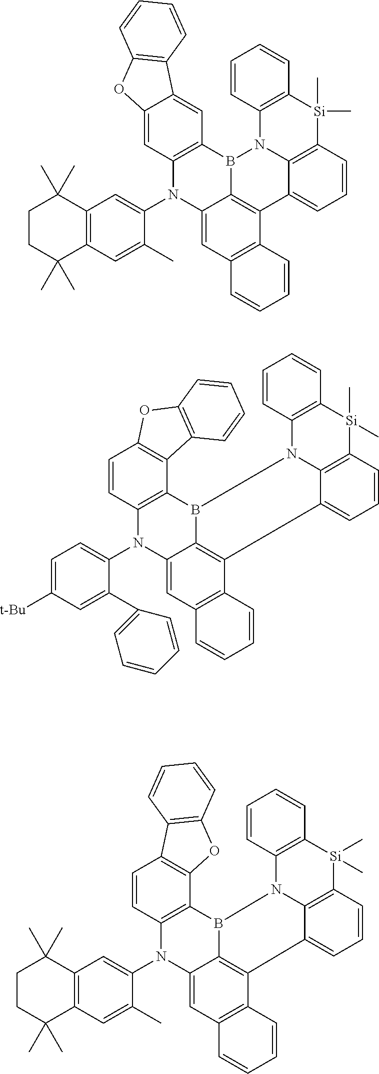 [SMILES: Cc1cc2c(cc1N1c3cc4oc5ccccc5c4cc3B3c4c1cc1ccccc1c4-c1cccc4c1N3c1ccccc1[Si]4(C)C)C(C)(C)CCC2(C)C ; CC(C)(C)c1ccc(N2c3cc4ccccc4c4c3B(c3c2ccc2oc5ccccc5c32)N2c3ccccc3[Si](C)(C)c3cccc-4c32)c(-c2ccccc2)c1 ; Cc1cc2c(cc1N1c3cc4ccccc4c4c3B(c3c1ccc1c3oc3ccccc31)N1c3ccccc3[Si](C)(C)c3cccc-4c31)C(C)(C)CCC2(C)C] 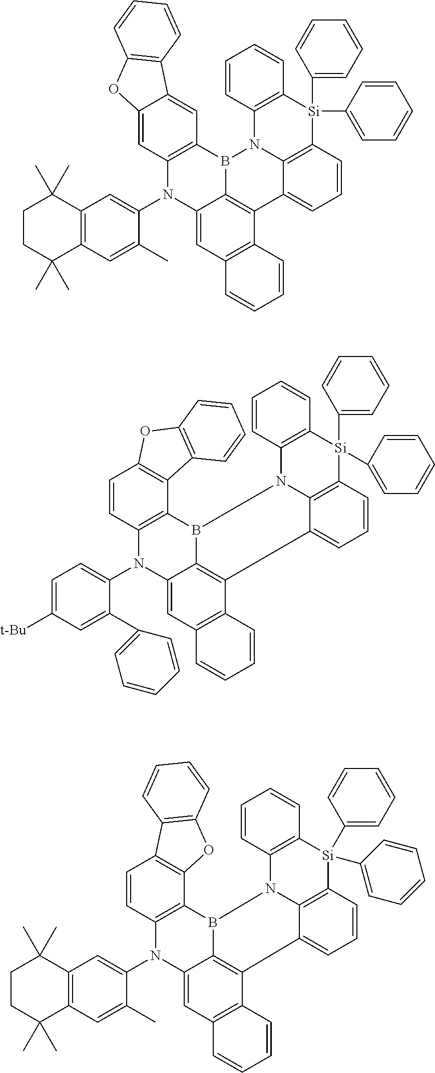 [SMILES: Cc1cc2c(cc1N1c3cc4oc5ccccc5c4cc3B3c4c1cc1ccccc1c4-c1cccc4c1N3c1ccccc1[Si]4(c1ccccc1)c1ccccc1)C(C)(C)CCC2(C)C ; CC(C)(C)c1ccc(N2c3cc4ccccc4c4c3B(c3c2ccc2oc5ccccc5c32)N2c3ccccc3[Si](c3ccccc3)(c3ccccc3)c3cccc-4c32)c(-c2ccccc2)c1 ; Cc1cc2c(cc1N1c3cc4ccccc4c4c3B(c3c1ccc1c3oc3ccccc31)N1c3ccccc3[Si](c3ccccc3)(c3ccccc3)c3cccc-4c31)C(C)(C)CCC2(C)C] 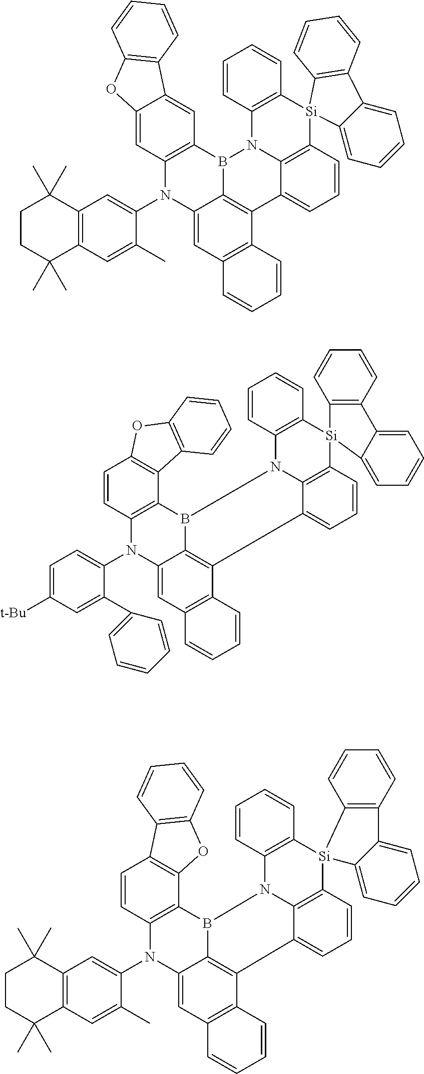 [SMILES: Cc1cc2c(cc1N1c3cc4oc5ccccc5c4cc3B3c4c1cc1ccccc1c4-c1cccc4c1N3c1ccccc1[Si]41c3ccccc3-c3ccccc31)C(C)(C)CCC2(C)C ; CC(C)(C)c1ccc(N2c3cc4ccccc4c4c3B(c3c2ccc2oc5ccccc5c32)N2c3ccccc3[Si]3(c5ccccc5-c5ccccc53)c3cccc-4c32)c(-c2ccccc2)c1 ; Cc1cc2c(cc1N1c3cc4ccccc4c4c3B(c3c1ccc1c3oc3ccccc31)N1c3ccccc3[Si]3(c5ccccc5-c5ccccc53)c3cccc-4c31)C(C)(C)CCC2(C)C] 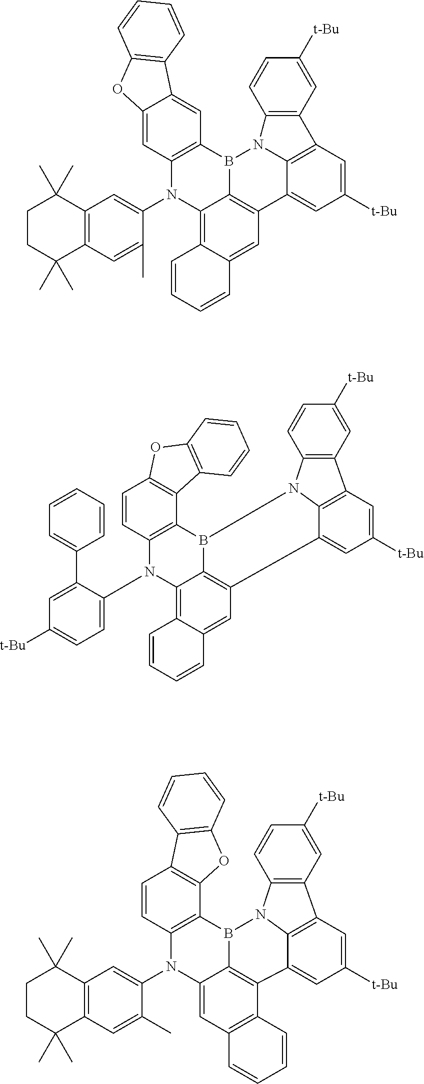 [SMILES: Cc1cc2c(cc1N1c3cc4oc5ccccc5c4cc3B3c4c(cc5ccccc5c41)-c1cc(C(C)(C)C)cc4c5cc(C(C)(C)C)ccc5n3c14)C(C)(C)CCC2(C)C ; CC(C)(C)c1ccc(N2c3ccc4oc5ccccc5c4c3B3c4c(cc5ccccc5c42)-c2cc(C(C)(C)C)cc4c5cc(C(C)(C)C)ccc5n3c24)c(-c2ccccc2)c1 ; Cc1cc2c(cc1N1c3cc4ccccc4c4c3B(c3c1ccc1c3oc3ccccc31)n1c3ccc(C(C)(C)C)cc3c3cc(C(C)(C)C)cc-4c31)C(C)(C)CCC2(C)C] 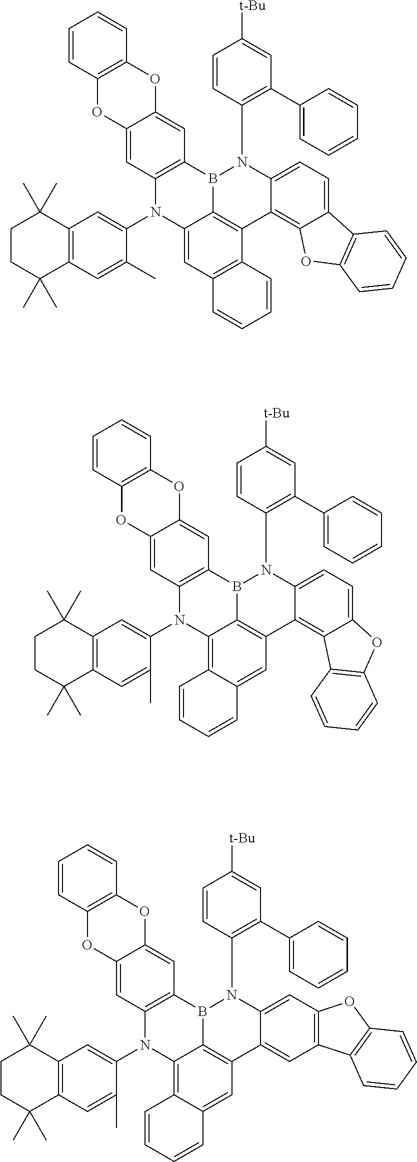 [SMILES: Cc1cc2c(cc1N1c3cc4c(cc3B3c5c1cc1ccccc1c5-c1c(ccc5c1oc1ccccc15)N3c1ccc(C(C)(C)C)cc1-c1ccccc1)Oc1ccccc1O4)C(C)(C)CCC2(C)C ; Cc1cc2c(cc1N1c3cc4c(cc3B3c5c(cc6ccccc6c51)-c1c(ccc5oc6ccccc6c15)N3c1ccc(C(C)(C)C)cc1-c1ccccc1)Oc1ccccc1O4)C(C)(C)CCC2(C)C ; Cc1cc2c(cc1N1c3cc4c(cc3B3c5c(cc6ccccc6c51)-c1cc5c(cc1N3c1ccc(C(C)(C)C)cc1-c1ccccc1)oc1ccccc15)Oc1ccccc1O4)C(C)(C)CCC2(C)C] 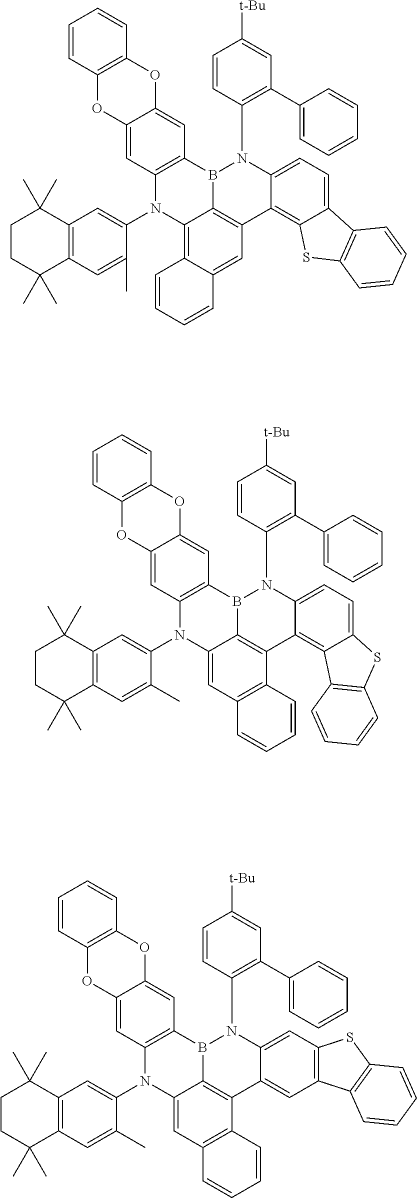 [SMILES: Cc1cc2c(cc1N1c3cc4c(cc3B3c5c(cc6ccccc6c51)-c1c(ccc5c1sc1ccccc15)N3c1ccc(C(C)(C)C)cc1-c1ccccc1)Oc1ccccc1O4)C(C)(C)CCC2(C)C ; Cc1cc2c(cc1N1c3cc4c(cc3B3c5c1cc1ccccc1c5-c1c(ccc5sc6ccccc6c15)N3c1ccc(C(C)(C)C)cc1-c1ccccc1)Oc1ccccc1O4)C(C)(C)CCC2(C)C ; Cc1cc2c(cc1N1c3cc4c(cc3B3c5c1cc1ccccc1c5-c1cc5c(cc1N3c1ccc(C(C)(C)C)cc1-c1ccccc1)sc1ccccc15)Oc1ccccc1O4)C(C)(C)CCC2(C)C] 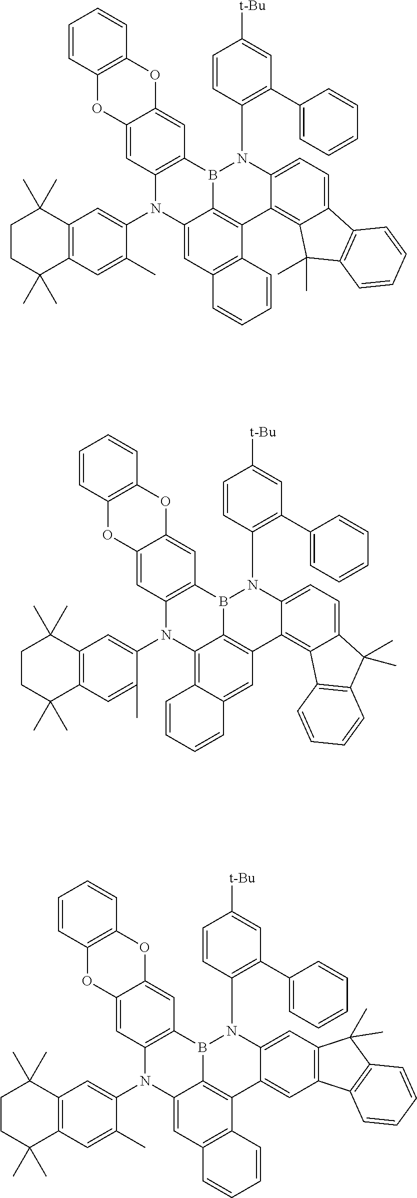 [SMILES: Cc1cc2c(cc1N1c3cc4c(cc3B3c5c1cc1ccccc1c5-c1c(ccc5c1C(C)(C)c1ccccc1-5)N3c1ccc(C(C)(C)C)cc1-c1ccccc1)Oc1ccccc1O4)C(C)(C)CCC2(C)C ; Cc1cc2c(cc1N1c3cc4c(cc3B3c5c(cc6ccccc6c51)-c1c(ccc5c1-c1ccccc1C5(C)C)N3c1ccc(C(C)(C)C)cc1-c1ccccc1)Oc1ccccc1O4)C(C)(C)CCC2(C)C ; Cc1cc2c(cc1N1c3cc4c(cc3B3c5c1cc1ccccc1c5-c1cc5c(cc1N3c1ccc(C(C)(C)C)cc1-c1ccccc1)C(C)(C)c1ccccc1-5)Oc1ccccc1O4)C(C)(C)CCC2(C)C] 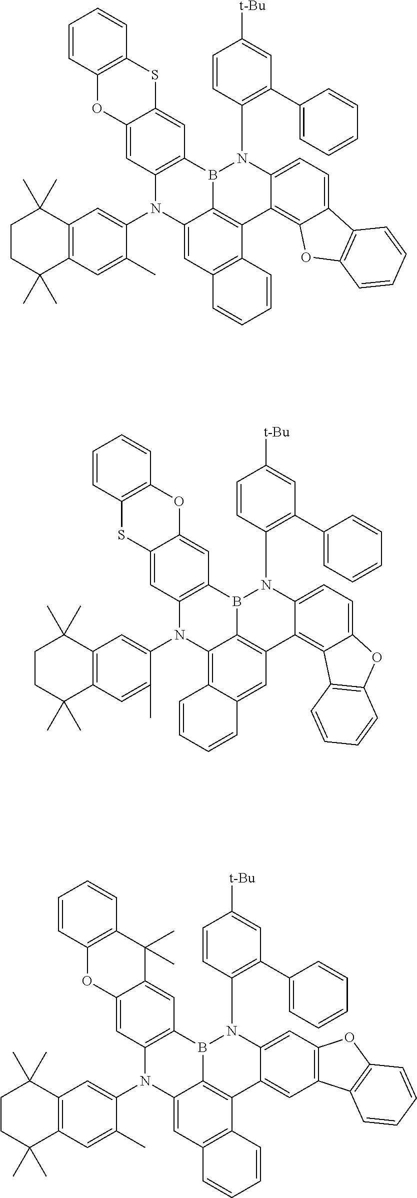 [SMILES: Cc1cc2c(cc1N1c3cc4c(cc3B3c5c1cc1ccccc1c5-c1c(ccc5c1oc1ccccc15)N3c1ccc(C(C)(C)C)cc1-c1ccccc1)Sc1ccccc1O4)C(C)(C)CCC2(C)C ; Cc1cc2c(cc1N1c3cc4c(cc3B3c5c(cc6ccccc6c51)-c1c(ccc5oc6ccccc6c15)N3c1ccc(C(C)(C)C)cc1-c1ccccc1)Oc1ccccc1S4)C(C)(C)CCC2(C)C ; Cc1cc2c(cc1N1c3cc4c(cc3B3c5c1cc1ccccc1c5-c1cc5c(cc1N3c1ccc(C(C)(C)C)cc1-c1ccccc1)oc1ccccc15)C(C)(C)c1ccccc1O4)C(C)(C)CCC2(C)C] 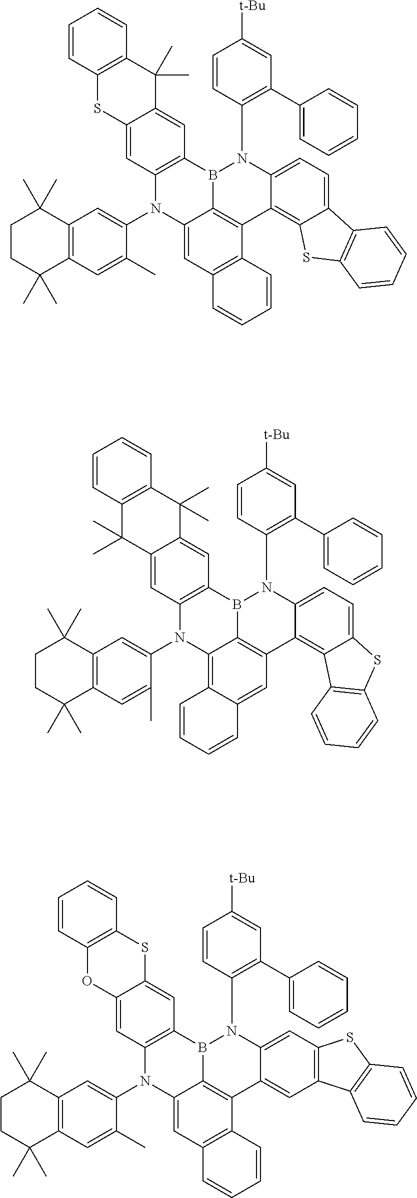 [SMILES: Cc1cc2c(cc1N1c3cc4c(cc3B3c5c1cc1ccccc1c5-c1c(ccc5c1sc1ccccc15)N3c1ccc(C(C)(C)C)cc1-c1ccccc1)C(C)(C)c1ccccc1S4)C(C)(C)CCC2(C)C ; Cc1cc2c(cc1N1c3cc4c(cc3B3c5c(cc6ccccc6c51)-c1c(ccc5sc6ccccc6c15)N3c1ccc(C(C)(C)C)cc1-c1ccccc1)C(C)(C)c1ccccc1C4(C)C)C(C)(C)CCC2(C)C ; Cc1cc2c(cc1N1c3cc4c(cc3B3c5c1cc1ccccc1c5-c1cc5c(cc1N3c1ccc(C(C)(C)C)cc1-c1ccccc1)sc1ccccc15)Sc1ccccc1O4)C(C)(C)CCC2(C)C] 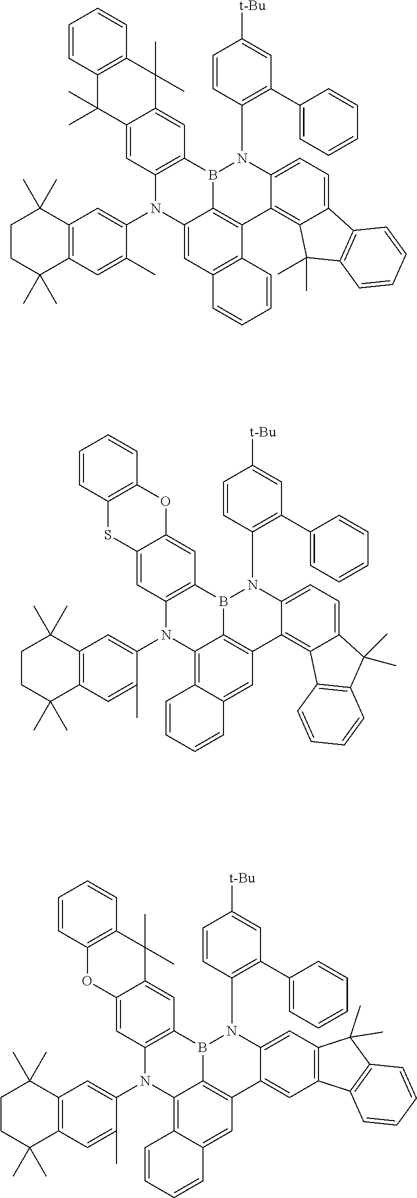 [SMILES: Cc1cc2c(cc1N1c3cc4c(cc3B3c5c1cc1ccccc1c5-c1c(ccc5c1C(C)(C)c1ccccc1-5)N3c1ccc(C(C)(C)C)cc1-c1ccccc1)C(C)(C)c1ccccc1C4(C)C)C(C)(C)CCC2(C)C ; Cc1cc2c(cc1N1c3cc4c(cc3B3c5c(cc6ccccc6c51)-c1c(ccc5c1-c1ccccc1C5(C)C)N3c1ccc(C(C)(C)C)cc1-c1ccccc1)Oc1ccccc1S4)C(C)(C)CCC2(C)C ; Cc1cc2c(cc1N1c3cc4c(cc3B3c5c(cc6ccccc6c51)-c1cc5c(cc1N3c1ccc(C(C)(C)C)cc1-c1ccccc1)C(C)(C)c1ccccc1-5)C(C)(C)c1ccccc1O4)C(C)(C)CCC2(C)C] 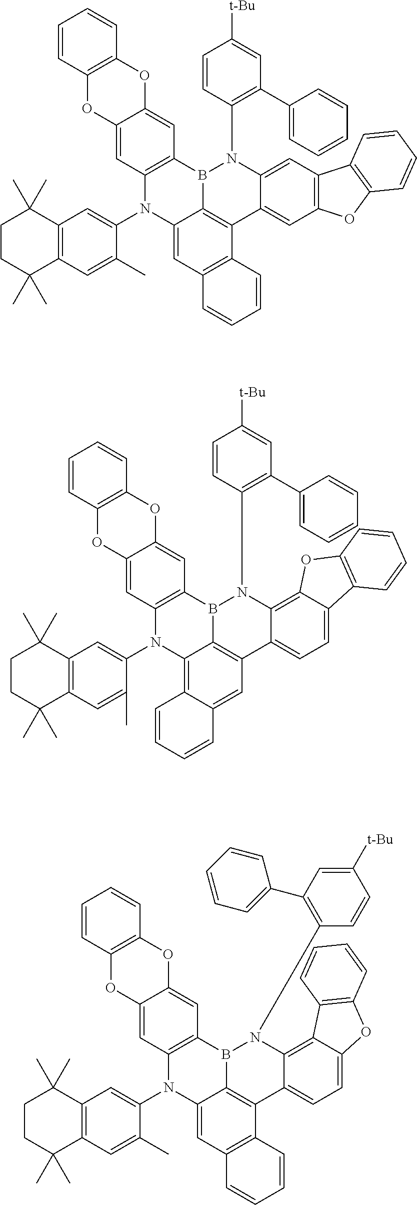 [SMILES: Cc1cc2c(cc1N1c3cc4c(cc3B3c5c1cc1ccccc1c5-c1cc5oc6ccccc6c5cc1N3c1ccc(C(C)(C)C)cc1-c1ccccc1)Oc1ccccc1O4)C(C)(C)CCC2(C)C ; Cc1cc2c(cc1N1c3cc4c(cc3B3c5c(cc6ccccc6c51)-c1ccc5c(oc6ccccc65)c1N3c1ccc(C(C)(C)C)cc1-c1ccccc1)Oc1ccccc1O4)C(C)(C)CCC2(C)C ; Cc1cc2c(cc1N1c3cc4c(cc3B3c5c1cc1ccccc1c5-c1ccc5oc6ccccc6c5c1N3c1ccc(C(C)(C)C)cc1-c1ccccc1)Oc1ccccc1O4)C(C)(C)CCC2(C)C] 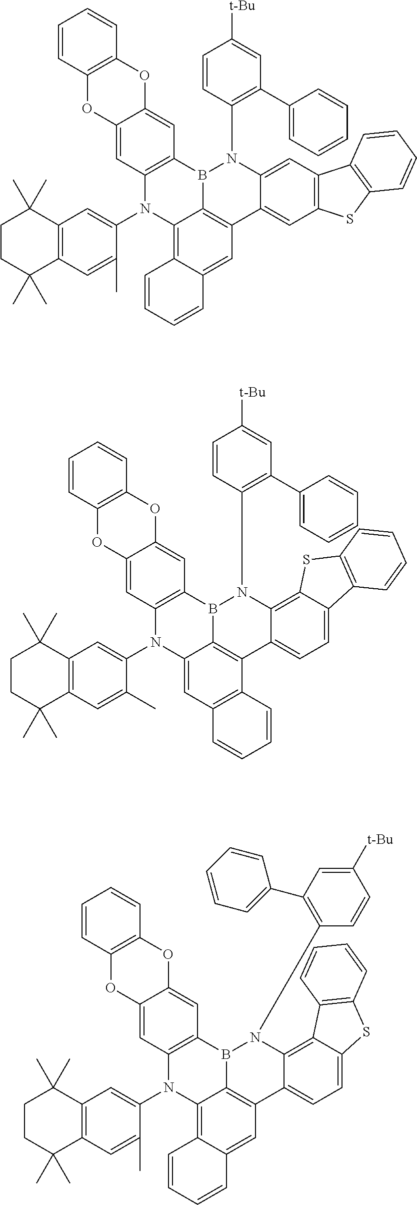 [SMILES: Cc1cc2c(cc1N1c3cc4c(cc3B3c5c(cc6ccccc6c51)-c1cc5sc6ccccc6c5cc1N3c1ccc(C(C)(C)C)cc1-c1ccccc1)Oc1ccccc1O4)C(C)(C)CCC2(C)C ; Cc1cc2c(cc1N1c3cc4c(cc3B3c5c1cc1ccccc1c5-c1ccc5c(sc6ccccc65)c1N3c1ccc(C(C)(C)C)cc1-c1ccccc1)Oc1ccccc1O4)C(C)(C)CCC2(C)C ; Cc1cc2c(cc1N1c3cc4c(cc3B3c5c(cc6ccccc6c51)-c1ccc5sc6ccccc6c5c1N3c1ccc(C(C)(C)C)cc1-c1ccccc1)Oc1ccccc1O4)C(C)(C)CCC2(C)C] 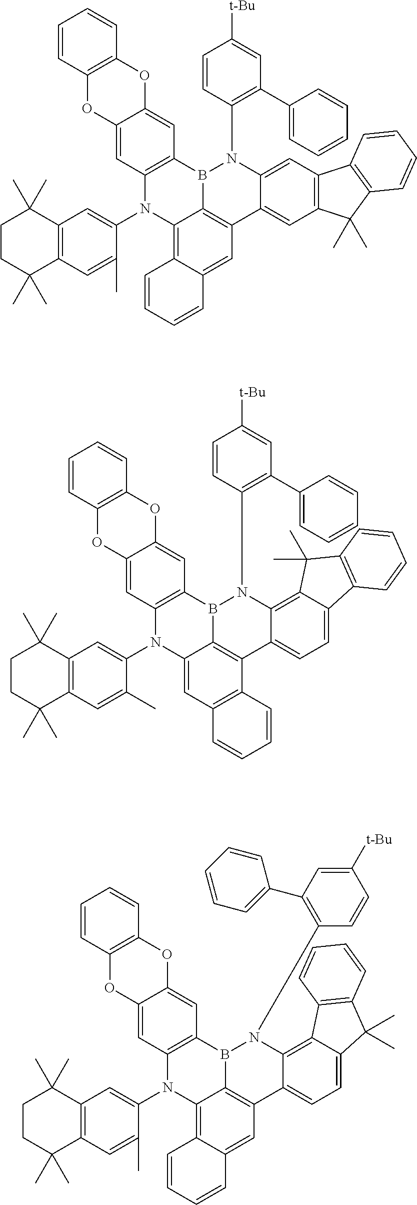 [SMILES: Cc1cc2c(cc1N1c3cc4c(cc3B3c5c(cc6ccccc6c51)-c1cc5c(cc1N3c1ccc(C(C)(C)C)cc1-c1ccccc1)-c1ccccc1C5(C)C)Oc1ccccc1O4)C(C)(C)CCC2(C)C ; Cc1cc2c(cc1N1c3cc4c(cc3B3c5c1cc1ccccc1c5-c1ccc5c(c1N3c1ccc(C(C)(C)C)cc1-c1ccccc1)C(C)(C)c1ccccc1-5)Oc1ccccc1O4)C(C)(C)CCC2(C)C ; Cc1cc2c(cc1N1c3cc4c(cc3B3c5c(cc6ccccc6c51)-c1ccc5c(c1N3c1ccc(C(C)(C)C)cc1-c1ccccc1)-c1ccccc1C5(C)C)Oc1ccccc1O4)C(C)(C)CCC2(C)C] 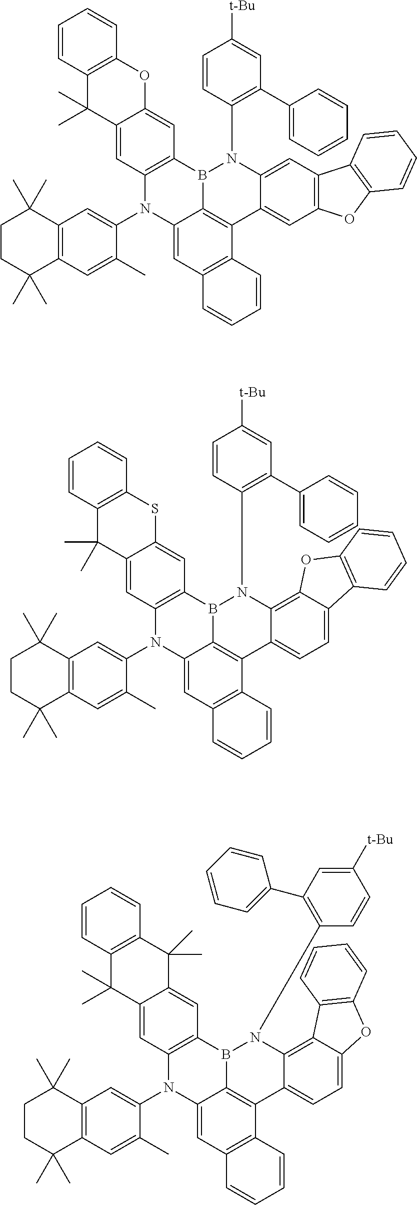 [SMILES: Cc1cc2c(cc1N1c3cc4c(cc3B3c5c1cc1ccccc1c5-c1cc5oc6ccccc6c5cc1N3c1ccc(C(C)(C)C)cc1-c1ccccc1)Oc1ccccc1C4(C)C)C(C)(C)CCC2(C)C ; Cc1cc2c(cc1N1c3cc4c(cc3B3c5c1cc1ccccc1c5-c1ccc5c(oc6ccccc65)c1N3c1ccc(C(C)(C)C)cc1-c1ccccc1)Sc1ccccc1C4(C)C)C(C)(C)CCC2(C)C ; Cc1cc2c(cc1N1c3cc4c(cc3B3c5c1cc1ccccc1c5-c1ccc5oc6ccccc6c5c1N3c1ccc(C(C)(C)C)cc1-c1ccccc1)C(C)(C)c1ccccc1C4(C)C)C(C)(C)CCC2(C)C] 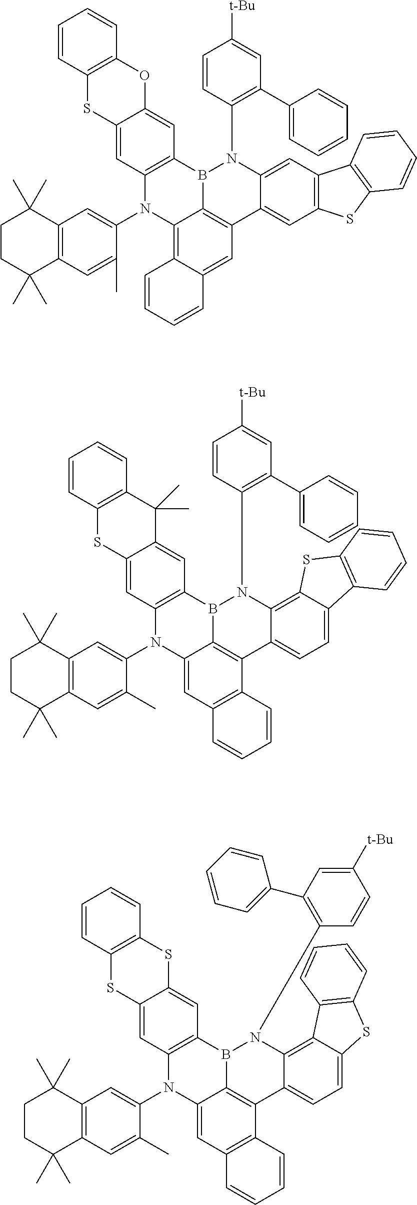 [SMILES: Cc1cc2c(cc1N1c3cc4c(cc3B3c5c(cc6ccccc6c51)-c1cc5sc6ccccc6c5cc1N3c1ccc(C(C)(C)C)cc1-c1ccccc1)Oc1ccccc1S4)C(C)(C)CCC2(C)C ; Cc1cc2c(cc1N1c3cc4c(cc3B3c5c1cc1ccccc1c5-c1ccc5c(sc6ccccc65)c1N3c1ccc(C(C)(C)C)cc1-c1ccccc1)C(C)(C)c1ccccc1S4)C(C)(C)CCC2(C)C ; Cc1cc2c(cc1N1c3cc4c(cc3B3c5c1cc1ccccc1c5-c1ccc5sc6ccccc6c5c1N3c1ccc(C(C)(C)C)cc1-c1ccccc1)Sc1ccccc1S4)C(C)(C)CCC2(C)C] 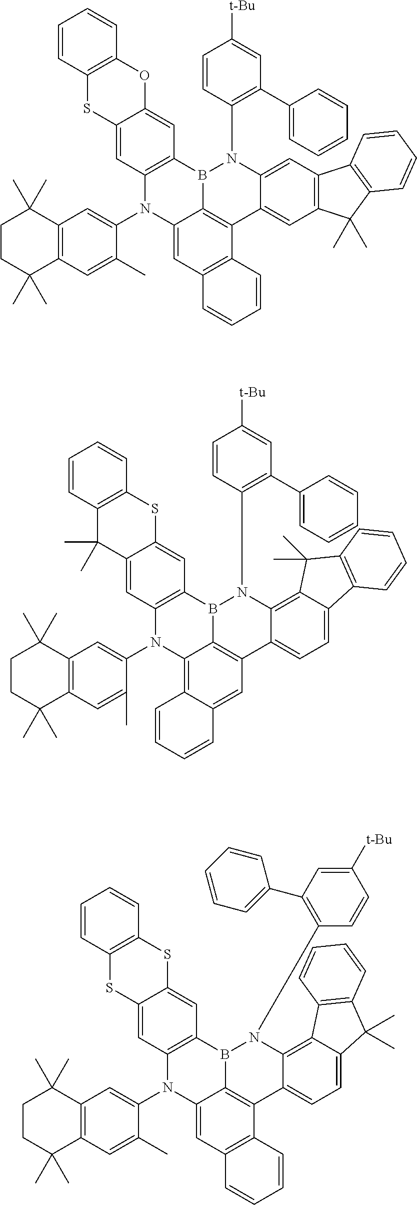 [SMILES: Cc1cc2c(cc1N1c3cc4c(cc3B3c5c1cc1ccccc1c5-c1cc5c(cc1N3c1ccc(C(C)(C)C)cc1-c1ccccc1)-c1ccccc1C5(C)C)Oc1ccccc1S4)C(C)(C)CCC2(C)C ; Cc1cc2c(cc1N1c3cc4c(cc3B3c5c(cc6ccccc6c51)-c1ccc5c(c1N3c1ccc(C(C)(C)C)cc1-c1ccccc1)C(C)(C)c1ccccc1-5)Sc1ccccc1C4(C)C)C(C)(C)CCC2(C)C ; Cc1cc2c(cc1N1c3cc4c(cc3B3c5c1cc1ccccc1c5-c1ccc5c(c1N3c1ccc(C(C)(C)C)cc1-c1ccccc1)-c1ccccc1C5(C)C)Sc1ccccc1S4)C(C)(C)CCC2(C)C] 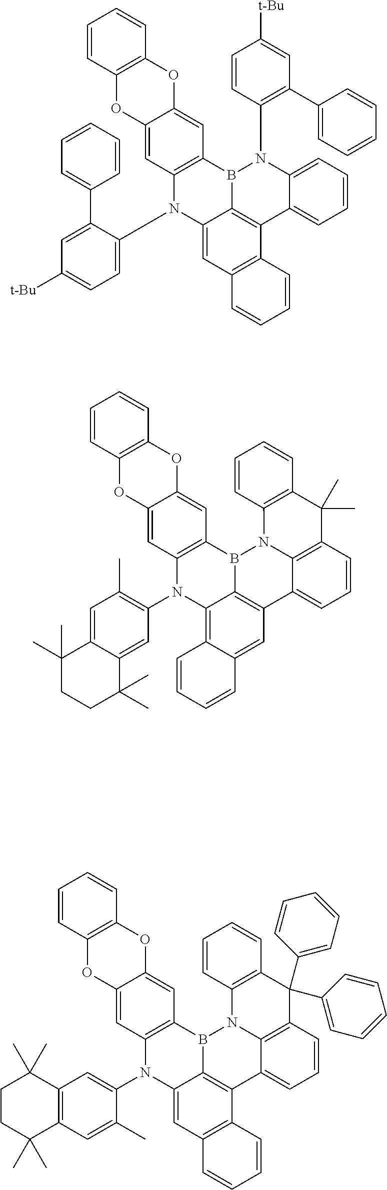 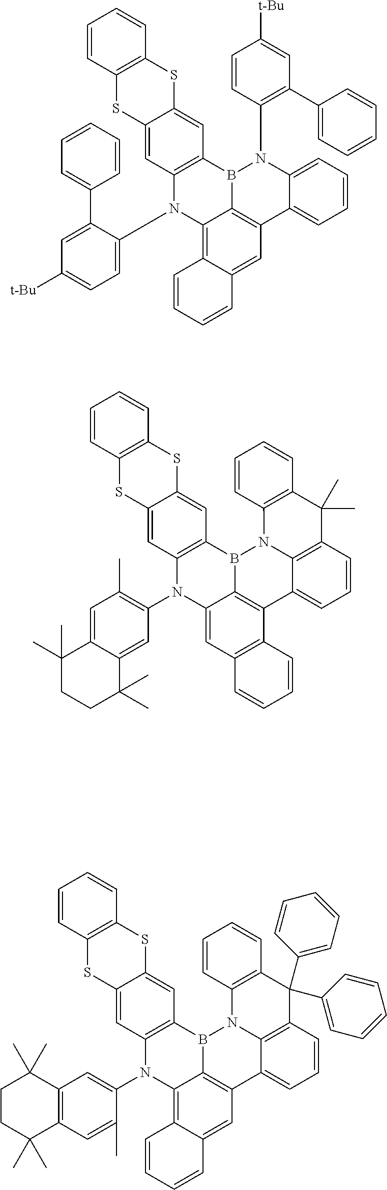 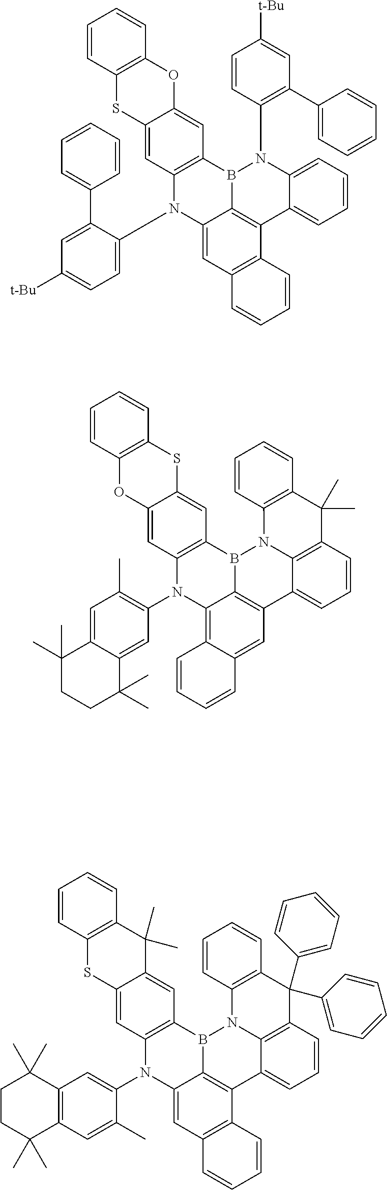 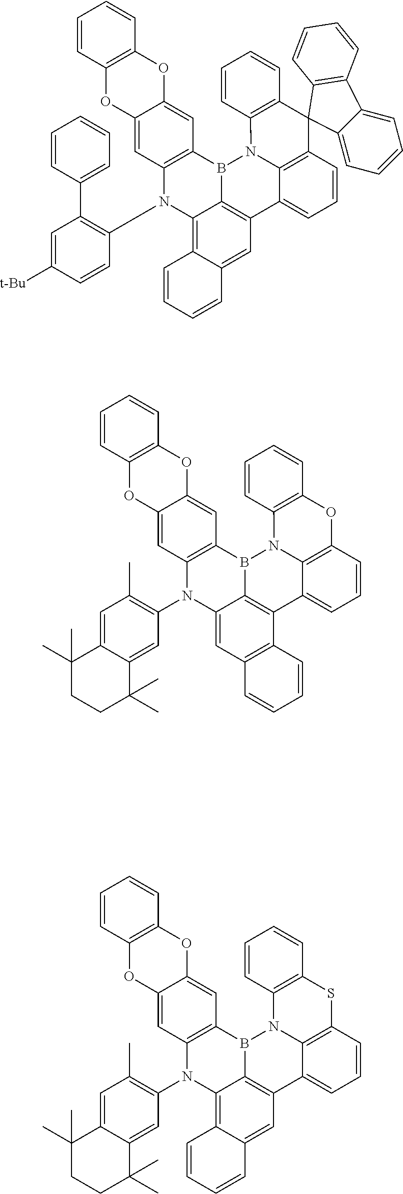 [SMILES: CC(C)(C)c1ccc(N2c3cc4c(cc3B3c5c(cc6ccccc6c52)-c2cccc5c2N3c2ccccc2C52c3ccccc3-c3ccccc32)Oc2ccccc2O4)c(-c2ccccc2)c1 ; Cc1cc2c(cc1N1c3cc4c(cc3B3c5c1cc1ccccc1c5-c1cccc5c1N3c1ccccc1O5)Oc1ccccc1O4)C(C)(C)CCC2(C)C ; Cc1cc2c(cc1N1c3cc4c(cc3B3c5c(cc6ccccc6c51)-c1cccc5c1N3c1ccccc1S5)Oc1ccccc1O4)C(C)(C)CCC2(C)C] 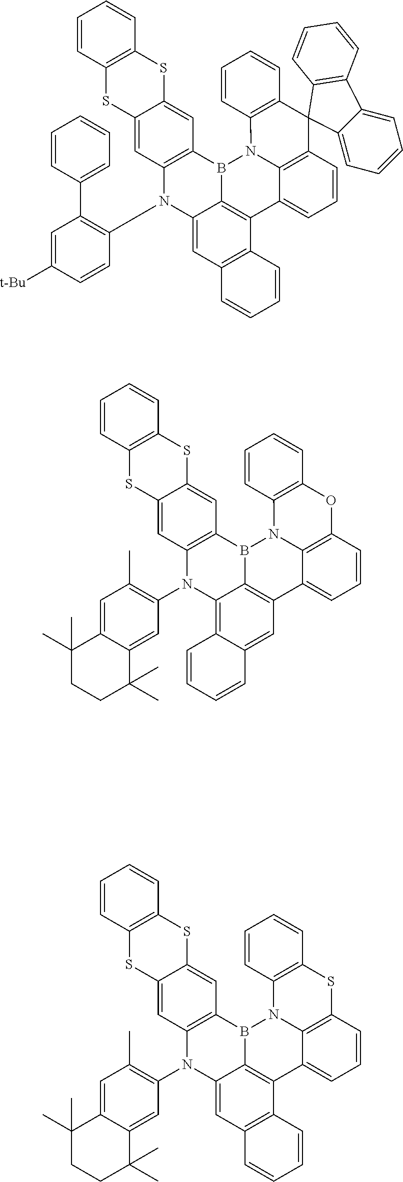 [SMILES: CC(C)(C)c1ccc(N2c3cc4c(cc3B3c5c2cc2ccccc2c5-c2cccc5c2N3c2ccccc2C52c3ccccc3-c3ccccc32)Sc2ccccc2S4)c(-c2ccccc2)c1 ; Cc1cc2c(cc1N1c3cc4c(cc3B3c5c(cc6ccccc6c51)-c1cccc5c1N3c1ccccc1O5)Sc1ccccc1S4)C(C)(C)CCC2(C)C ; Cc1cc2c(cc1N1c3cc4c(cc3B3c5c1cc1ccccc1c5-c1cccc5c1N3c1ccccc1S5)Sc1ccccc1S4)C(C)(C)CCC2(C)C] 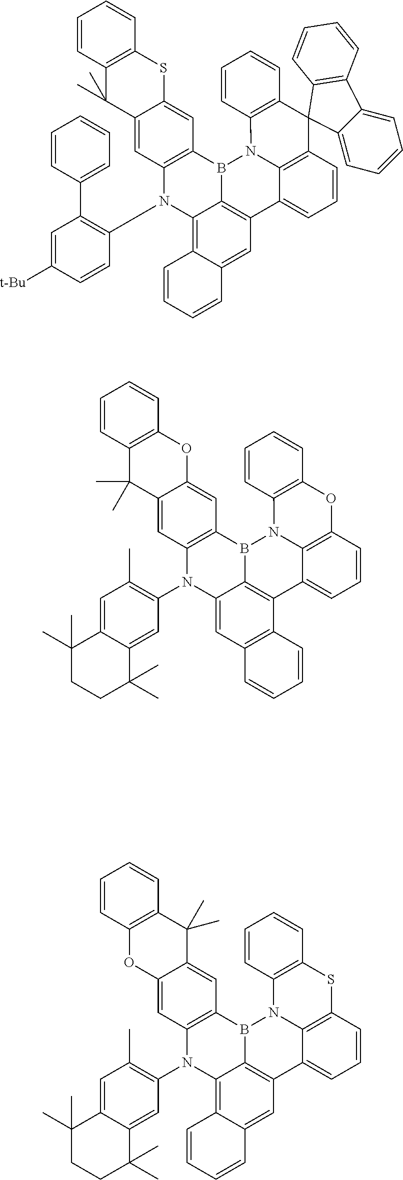 [SMILES: CC(C)(C)c1ccc(N2c3cc4c(cc3B3c5c(cc6ccccc6c52)-c2cccc5c2N3c2ccccc2C52c3ccccc3-c3ccccc32)Sc2ccccc2C4(C)C)c(-c2ccccc2)c1 ; Cc1cc2c(cc1N1c3cc4c(cc3B3c5c1cc1ccccc1c5-c1cccc5c1N3c1ccccc1O5)Oc1ccccc1C4(C)C)C(C)(C)CCC2(C)C ; Cc1cc2c(cc1N1c3cc4c(cc3B3c5c(cc6ccccc6c51)-c1cccc5c1N3c1ccccc1S5)C(C)(C)c1ccccc1O4)C(C)(C)CCC2(C)C] 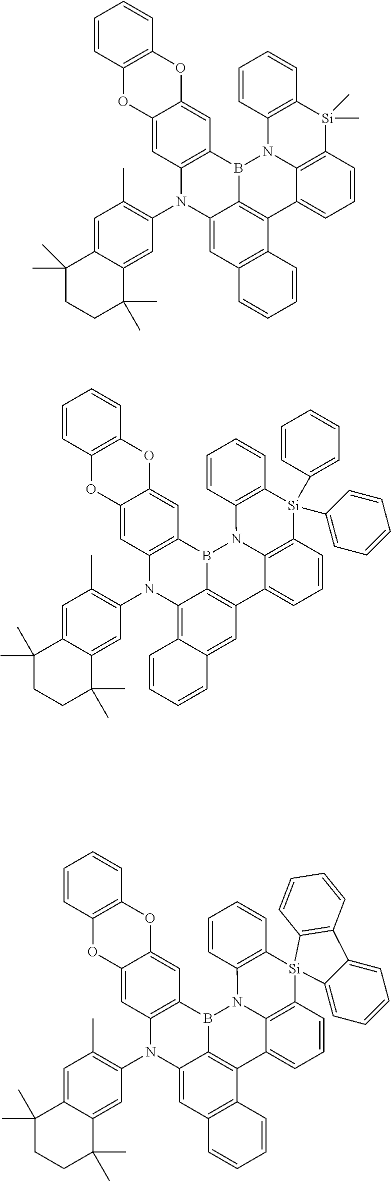 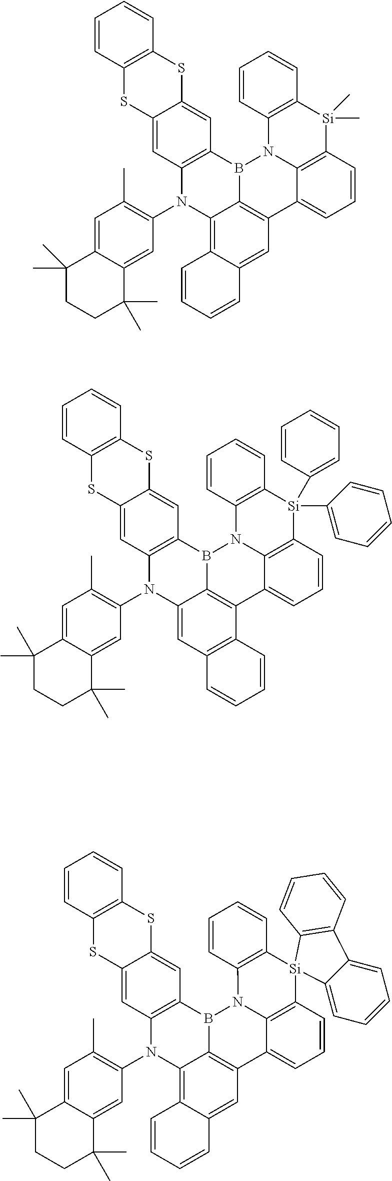 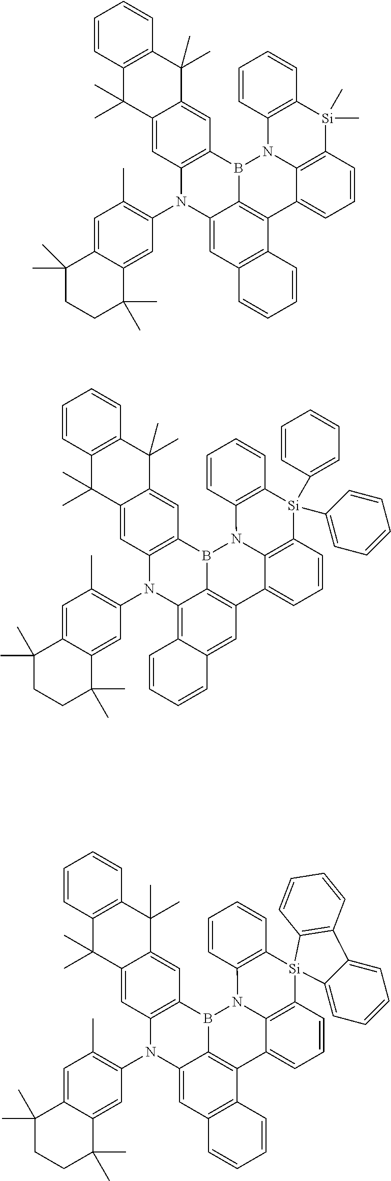 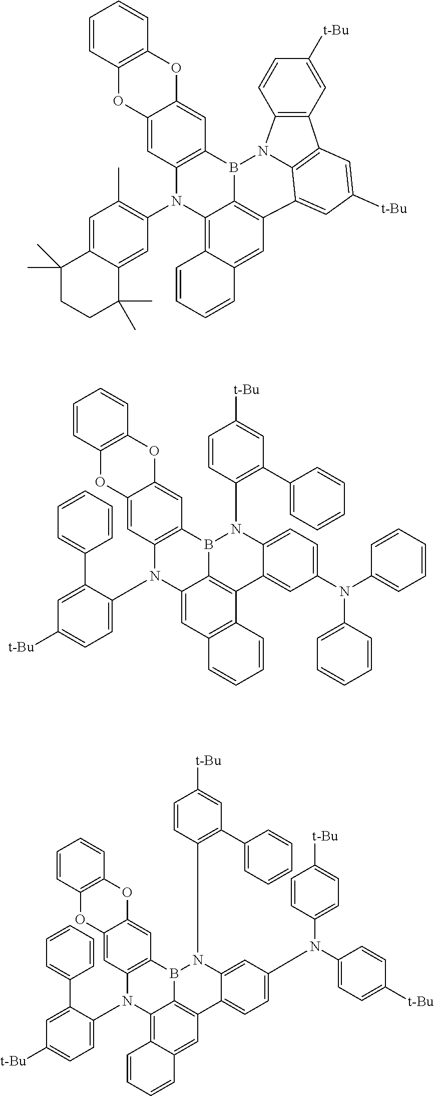 [SMILES: Cc1cc2c(cc1N1c3cc4c(cc3B3c5c(cc6ccccc6c51)-c1cc(C(C)(C)C)cc5c6cc(C(C)(C)C)ccc6n3c15)Oc1ccccc1O4)C(C)(C)CCC2(C)C ; CC(C)(C)c1ccc(N2B3c4cc5c(cc4N(c4ccc(C(C)(C)C)cc4-c4ccccc4)c4cc6ccccc6c(c43)-c3cc(N(c4ccccc4)c4ccccc4)ccc32)Oc2ccccc2O5)c(-c2ccccc2)c1 ; CC(C)(C)c1ccc(N(c2ccc(C(C)(C)C)cc2)c2ccc3c(c2)N(c2ccc(C(C)(C)C)cc2-c2ccccc2)B2c4cc5c(cc4N(c4ccc(C(C)(C)C)cc4-c4ccccc4)c4c2c-3cc2ccccc42)Oc2ccccc2O5)cc1] 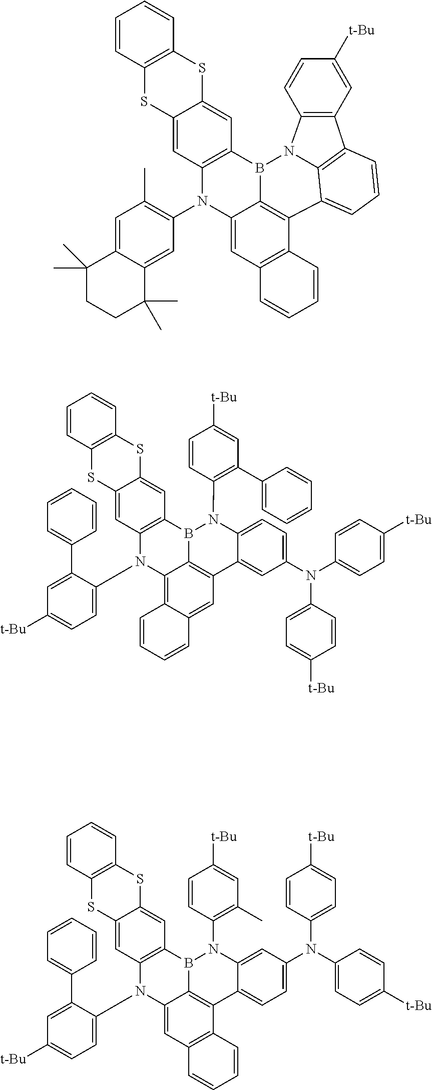 [SMILES: Cc1cc2c(cc1N1c3cc4c(cc3B3c5c1cc1ccccc1c5-c1cccc5c6cc(C(C)(C)C)ccc6n3c15)Sc1ccccc1S4)C(C)(C)CCC2(C)C ; CC(C)(C)c1ccc(N(c2ccc(C(C)(C)C)cc2)c2ccc3c(c2)-c2cc4ccccc4c4c2B(c2cc5c(cc2N4c2ccc(C(C)(C)C)cc2-c2ccccc2)Sc2ccccc2S5)N3c2ccc(C(C)(C)C)cc2-c2ccccc2)cc1 ; Cc1cc(C(C)(C)C)ccc1N1B2c3cc4c(cc3N(c3ccc(C(C)(C)C)cc3-c3ccccc3)c3cc5ccccc5c(c32)-c2ccc(N(c3ccc(C(C)(C)C)cc3)c3ccc(C(C)(C)C)cc3)cc21)Sc1ccccc1S4] 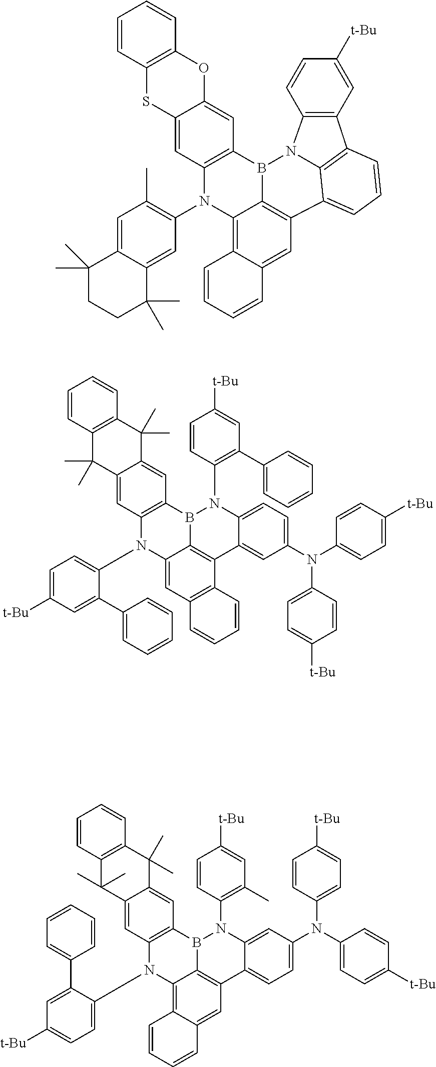 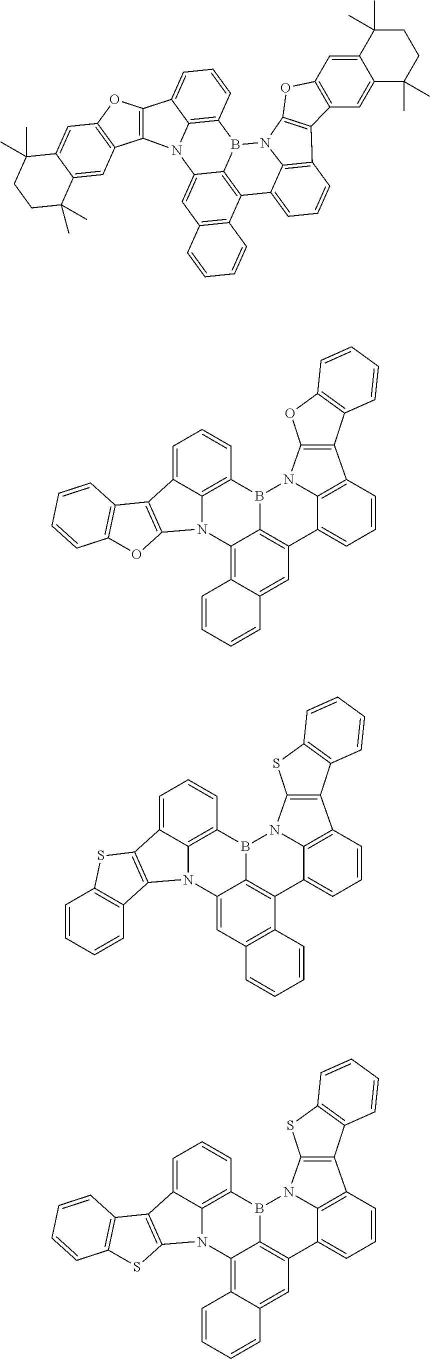 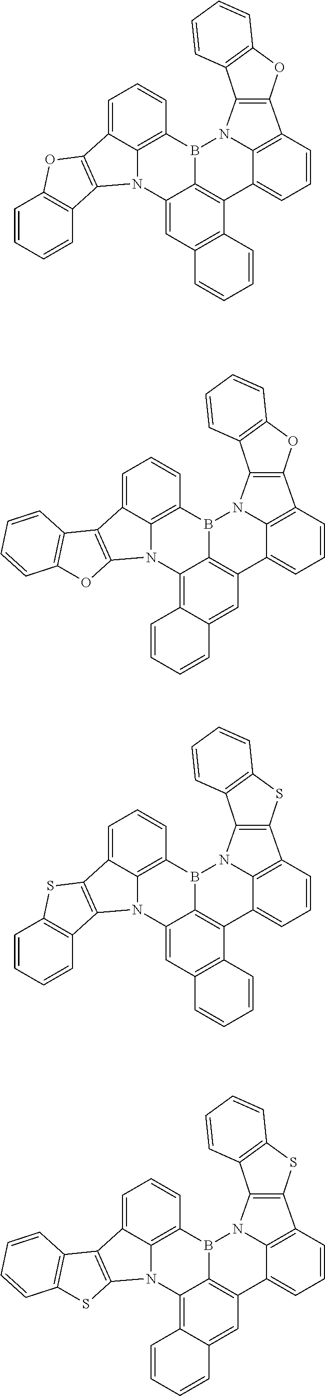 [SMILES: c1ccc2c3c4c(cc2c1)-n1c2c(cccc2c2oc5ccccc5c21)B4n1c2c-3cccc2c2oc3ccccc3c21 ; c1ccc2c3c4c(cc2c1)-c1cccc2c5oc6ccccc6c5n(c12)B4c1cccc2c4c5ccccc5oc4n-3c12 ; c1ccc2c3c4c(cc2c1)-n1c2c(cccc2c2sc5ccccc5c21)B4n1c2c-3cccc2c2sc3ccccc3c21 ; c1ccc2c3c4c(cc2c1)-c1cccc2c5sc6ccccc6c5n(c12)B4c1cccc2c4c5ccccc5sc4n-3c12] 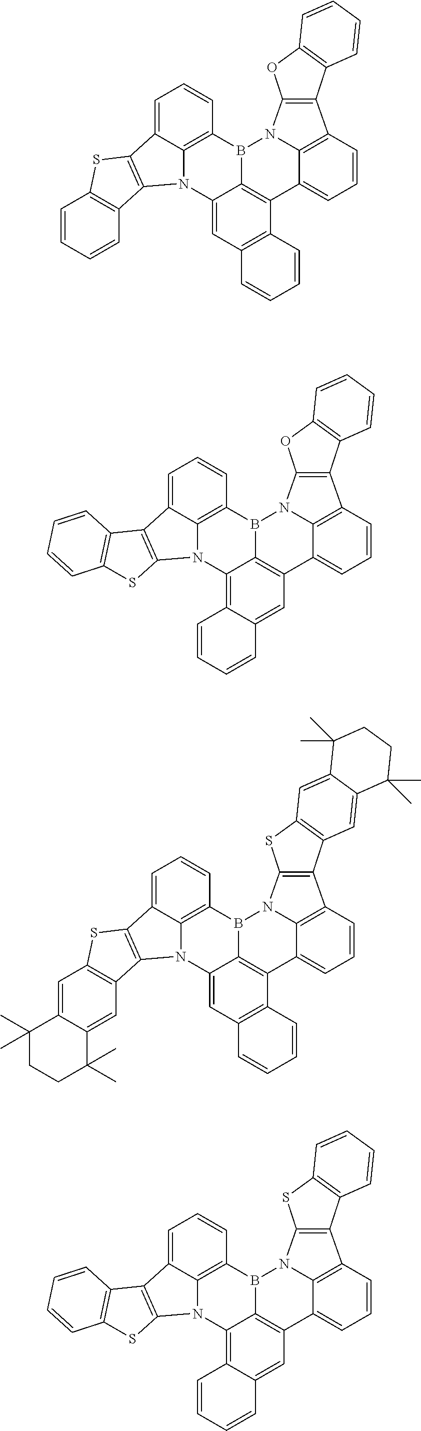 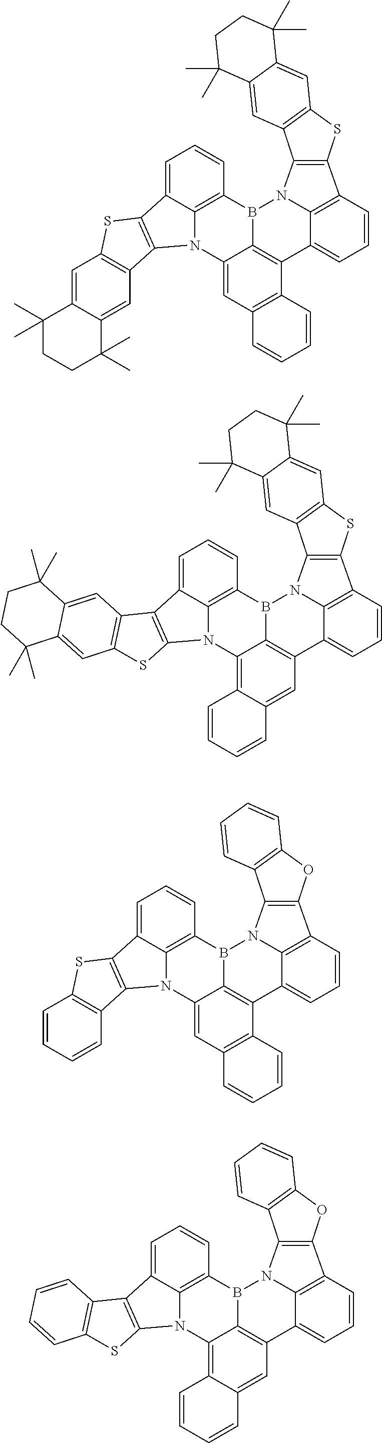 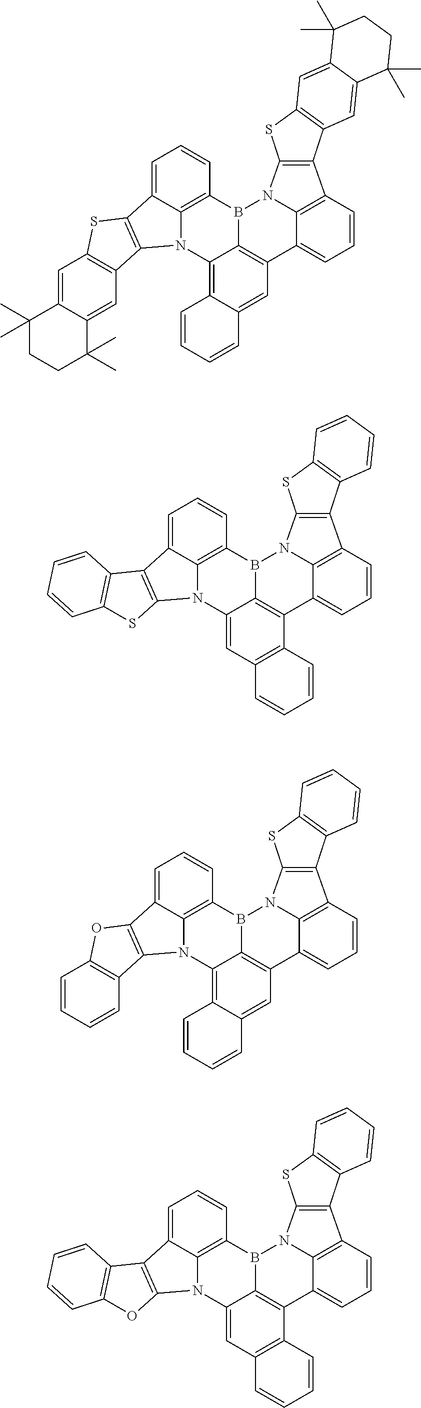 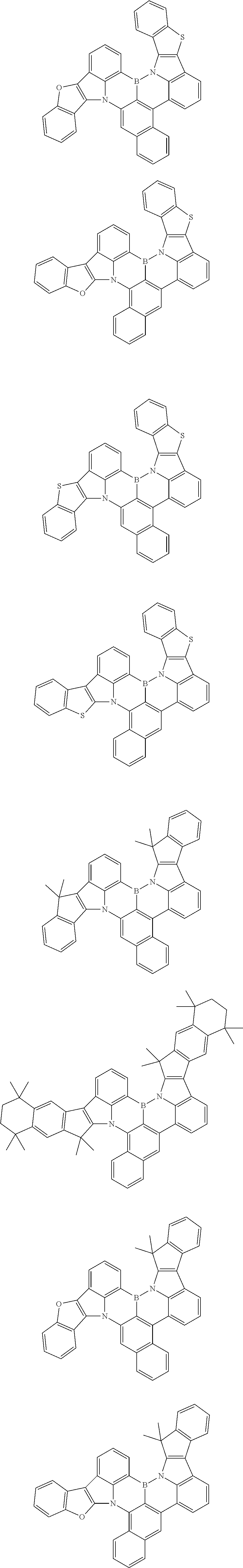 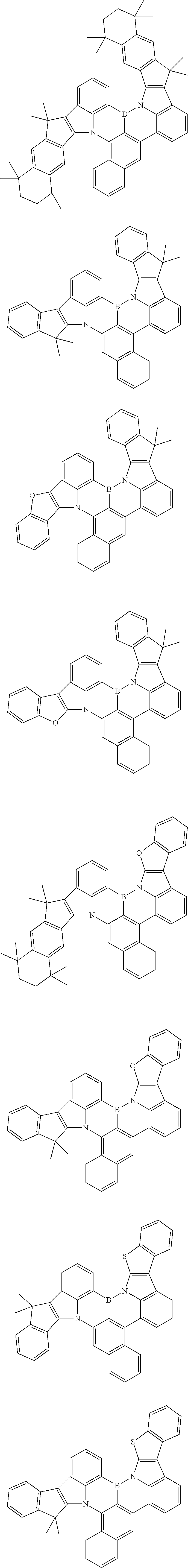 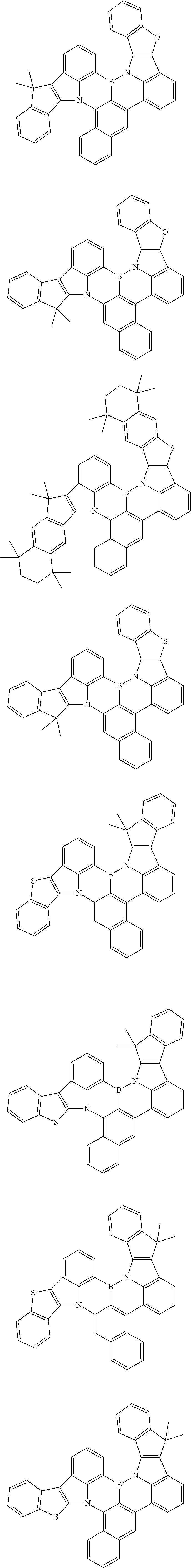 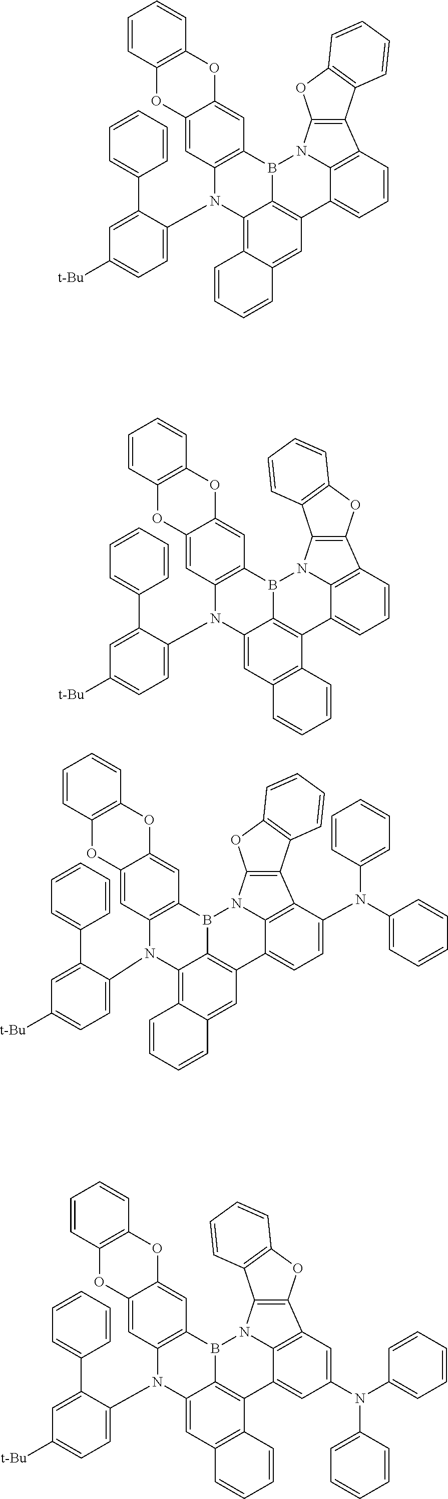 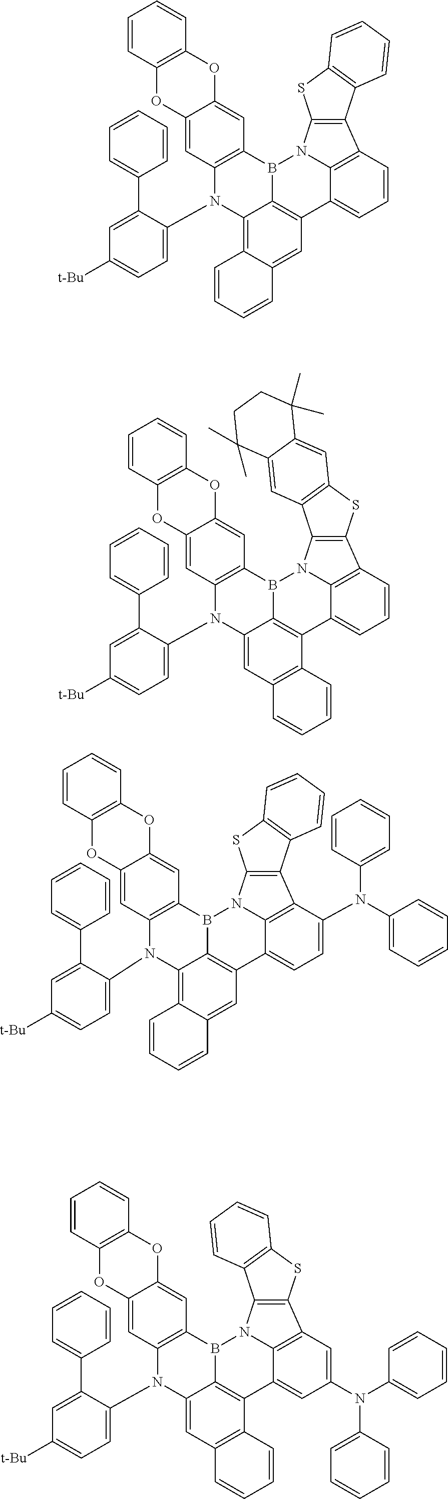 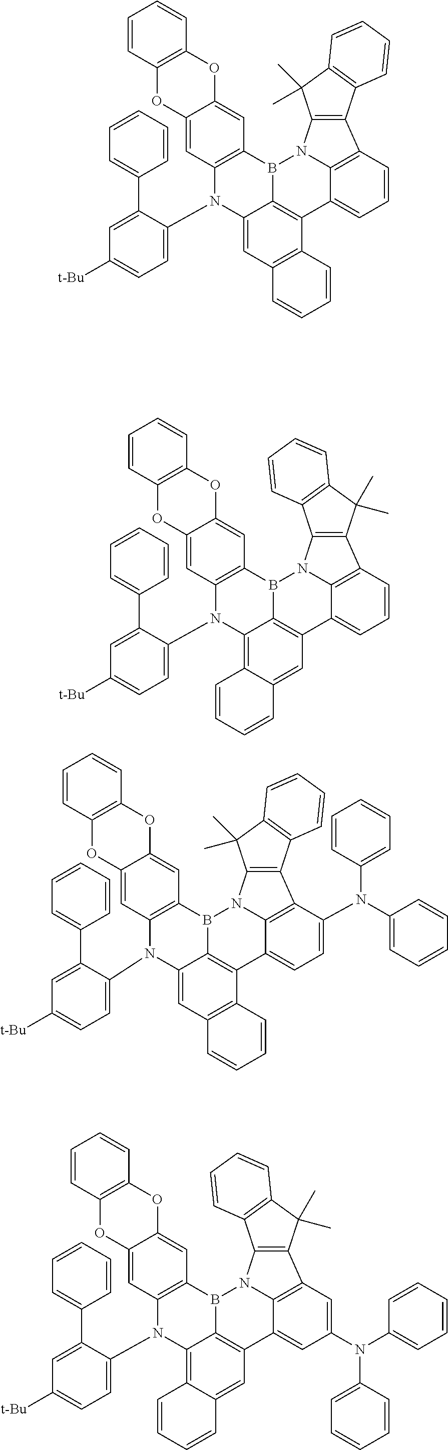 [SMILES: CC(C)(C)c1ccc(N2c3cc4c(cc3B3c5c2cc2ccccc2c5-c2cccc5c6c(n3c25)C(C)(C)c2ccccc2-6)Oc2ccccc2O4)c(-c2ccccc2)c1 ; CC(C)(C)c1ccc(N2c3cc4c(cc3B3c5c(cc6ccccc6c52)-c2cccc5c6c(n3c25)-c2ccccc2C6(C)C)Oc2ccccc2O4)c(-c2ccccc2)c1 ; CC(C)(C)c1ccc(N2c3cc4c(cc3B3c5c2cc2ccccc2c5-c2ccc(N(c5ccccc5)c5ccccc5)c5c6c(n3c25)C(C)(C)c2ccccc2-6)Oc2ccccc2O4)c(-c2ccccc2)c1 ; CC(C)(C)c1ccc(N2c3cc4c(cc3B3c5c(cc6ccccc6c52)-c2cc(N(c5ccccc5)c5ccccc5)cc5c6c(n3c25)-c2ccccc2C6(C)C)Oc2ccccc2O4)c(-c2ccccc2)c1] 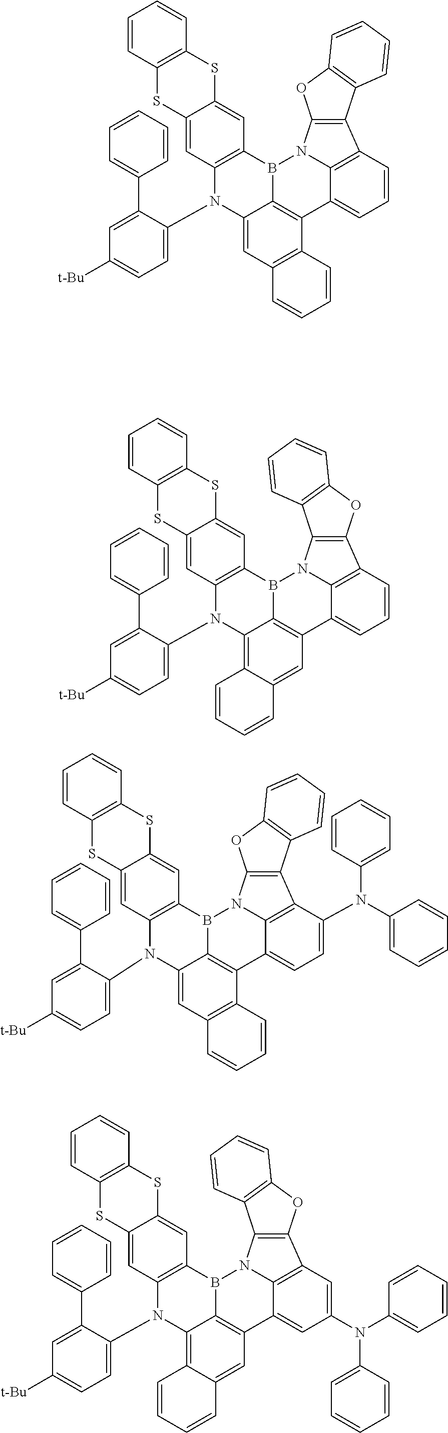 [SMILES: CC(C)(C)c1ccc(N2c3cc4c(cc3B3c5c2cc2ccccc2c5-c2cccc5c6c7ccccc7oc6n3c25)Sc2ccccc2S4)c(-c2ccccc2)c1 ; CC(C)(C)c1ccc(N2c3cc4c(cc3B3c5c(cc6ccccc6c52)-c2cccc5c6oc7ccccc7c6n3c25)Sc2ccccc2S4)c(-c2ccccc2)c1 ; CC(C)(C)c1ccc(N2c3cc4c(cc3B3c5c2cc2ccccc2c5-c2ccc(N(c5ccccc5)c5ccccc5)c5c6c7ccccc7oc6n3c25)Sc2ccccc2S4)c(-c2ccccc2)c1 ; CC(C)(C)c1ccc(N2c3cc4c(cc3B3c5c(cc6ccccc6c52)-c2cc(N(c5ccccc5)c5ccccc5)cc5c6oc7ccccc7c6n3c25)Sc2ccccc2S4)c(-c2ccccc2)c1] 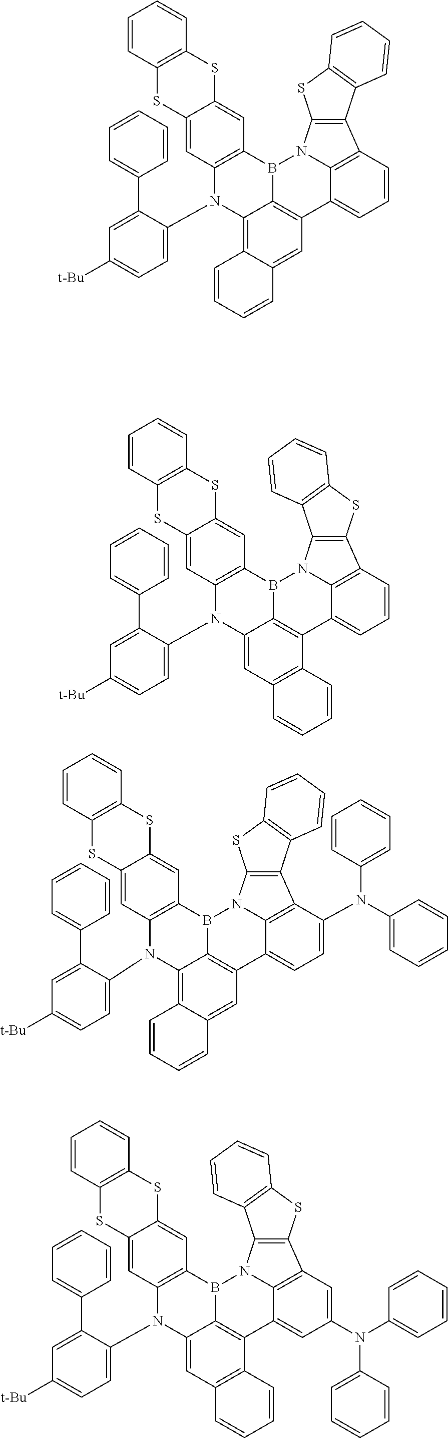 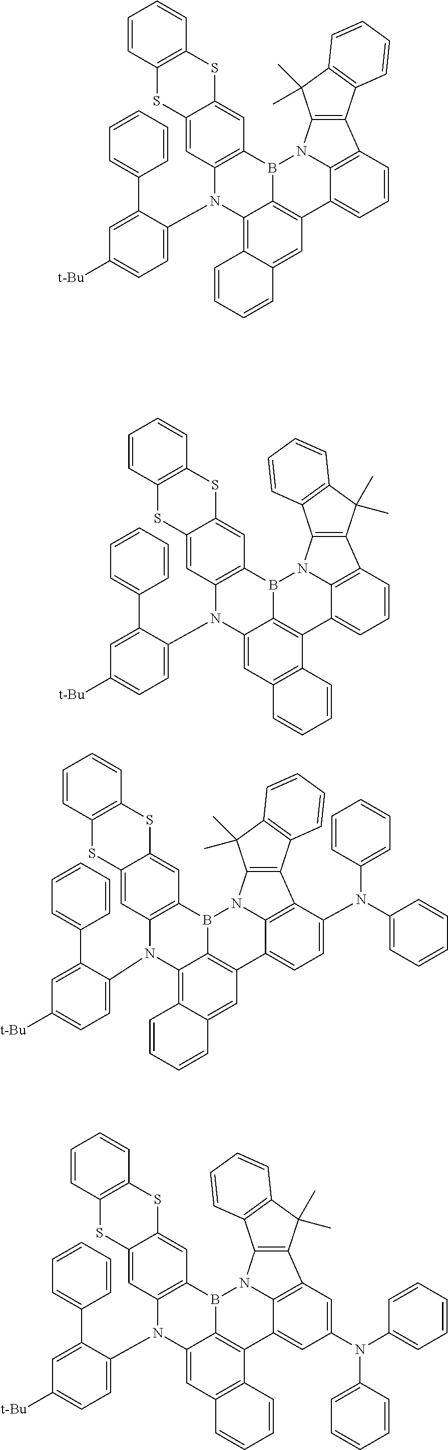 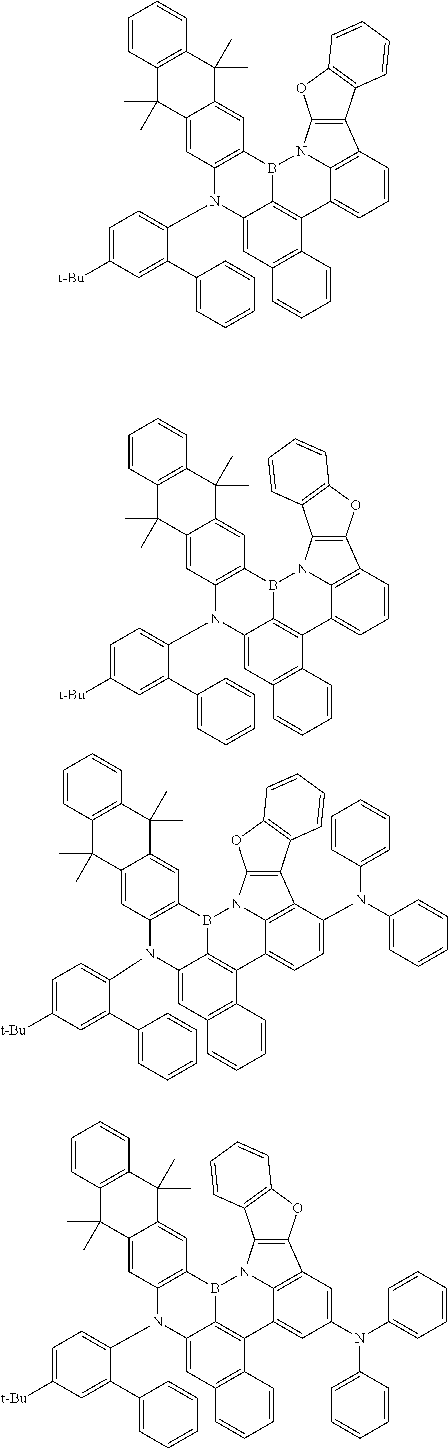 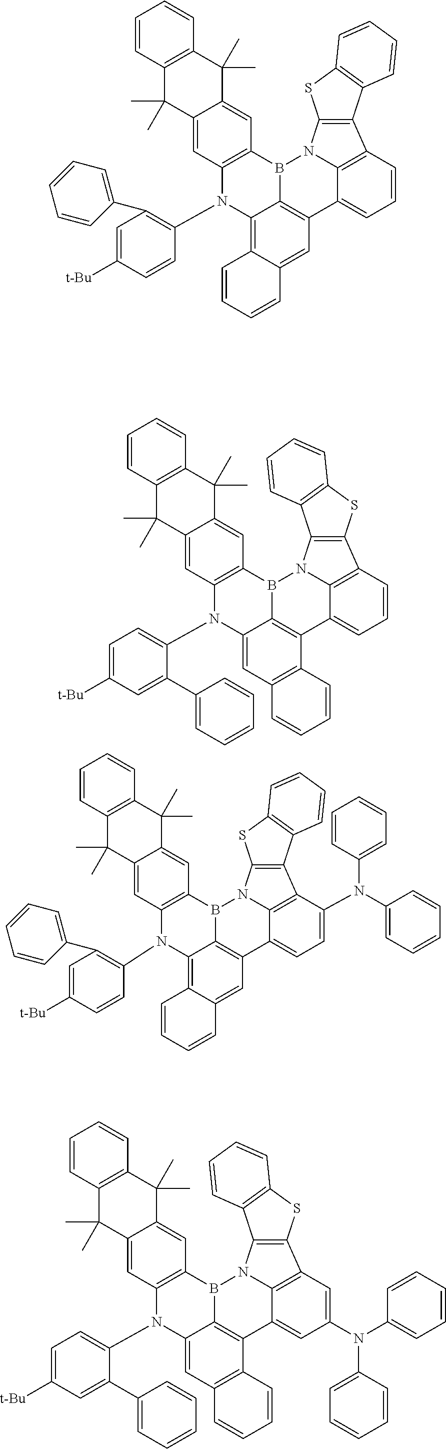 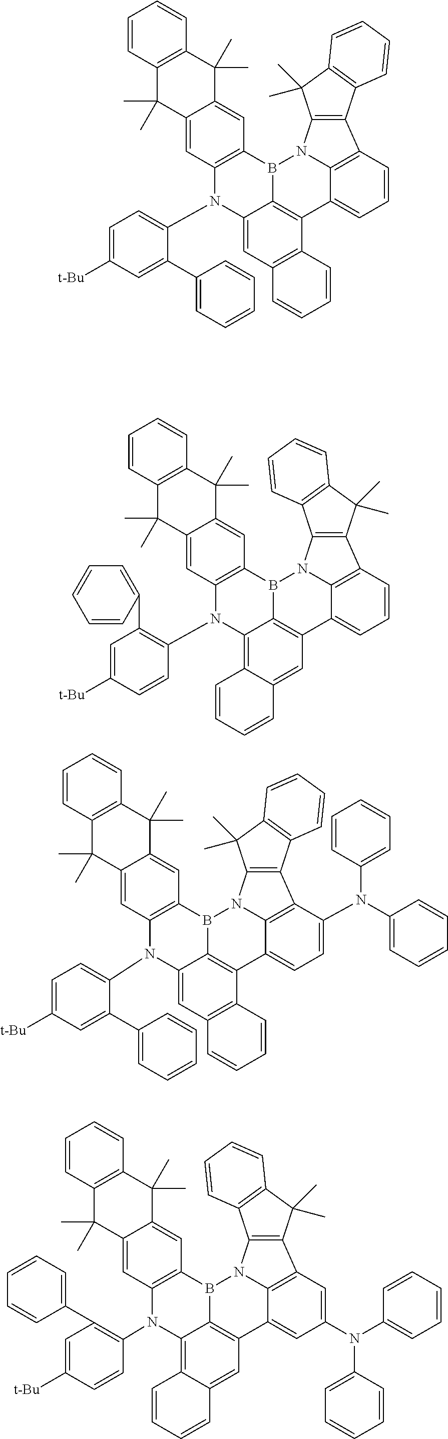 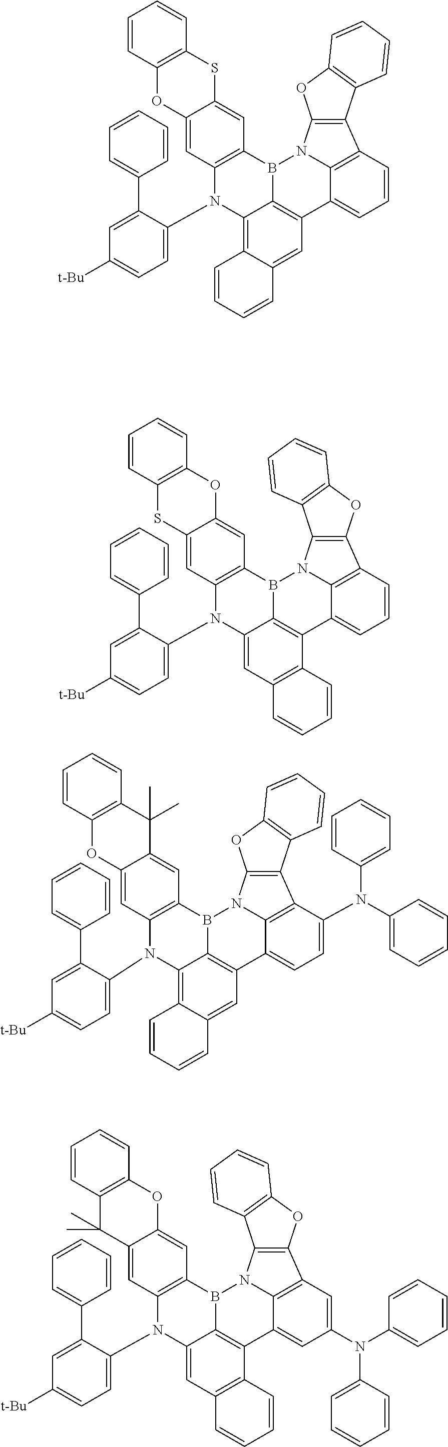 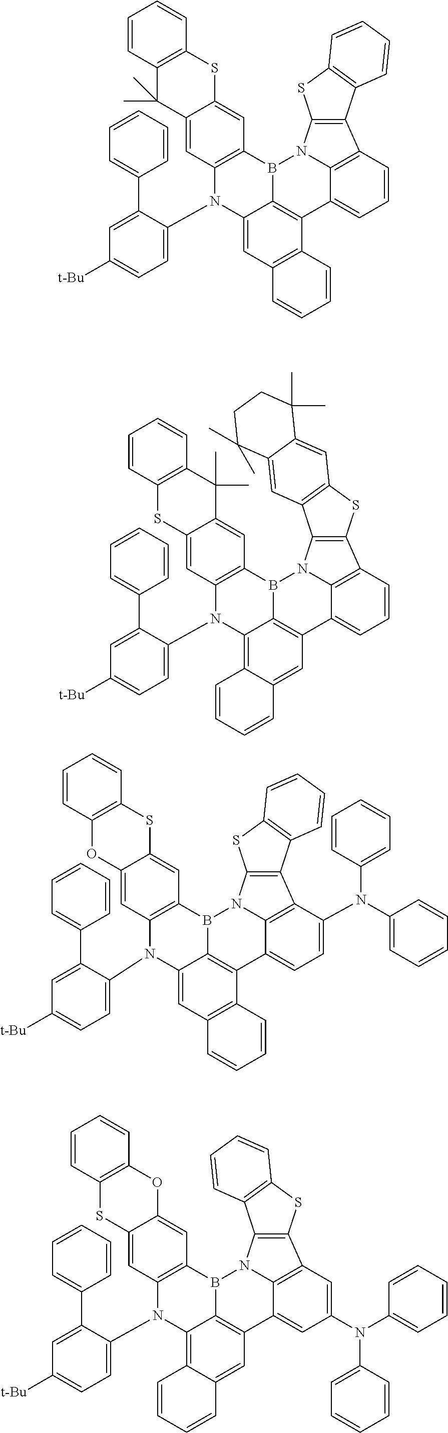 [SMILES: CC(C)(C)c1ccc(N2c3cc4c(cc3B3c5c2cc2ccccc2c5-c2cccc5c6c7ccccc7sc6n3c25)Sc2ccccc2C4(C)C)c(-c2ccccc2)c1 ; CC(C)(C)c1ccc(N2c3cc4c(cc3B3c5c(cc6ccccc6c52)-c2cccc5c6sc7cc8c(cc7c6n3c25)C(C)(C)CCC8(C)C)C(C)(C)c2ccccc2S4)c(-c2ccccc2)c1 ; CC(C)(C)c1ccc(N2c3cc4c(cc3B3c5c2cc2ccccc2c5-c2ccc(N(c5ccccc5)c5ccccc5)c5c6c7ccccc7sc6n3c25)Sc2ccccc2O4)c(-c2ccccc2)c1 ; CC(C)(C)c1ccc(N2c3cc4c(cc3B3c5c(cc6ccccc6c52)-c2cc(N(c5ccccc5)c5ccccc5)cc5c6sc7ccccc7c6n3c25)Oc2ccccc2S4)c(-c2ccccc2)c1] 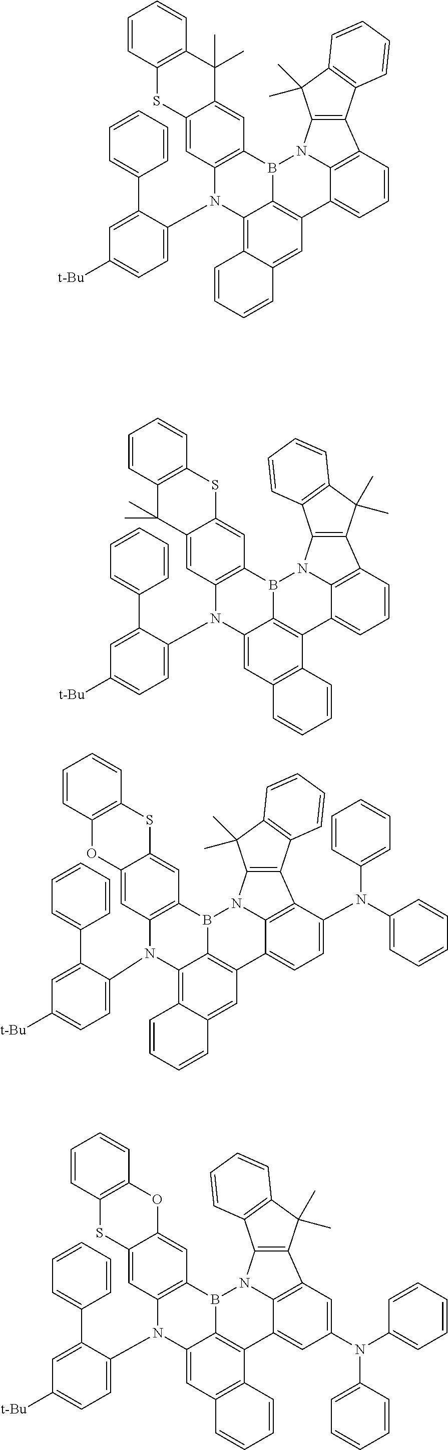 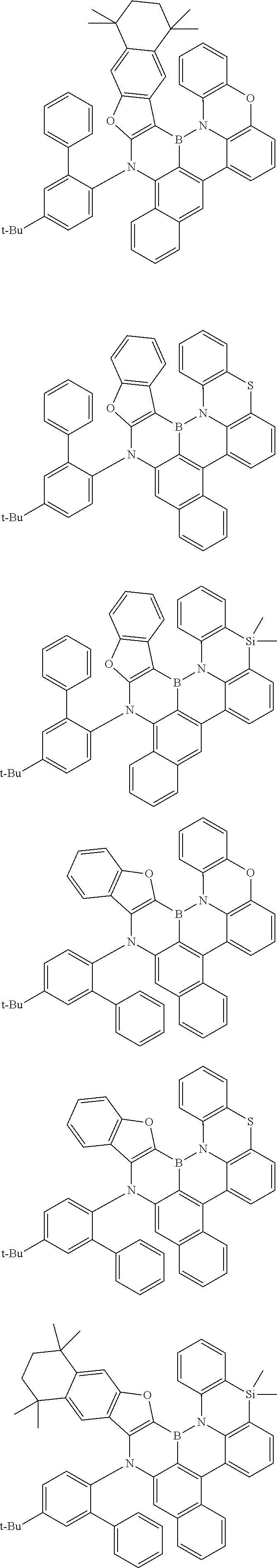 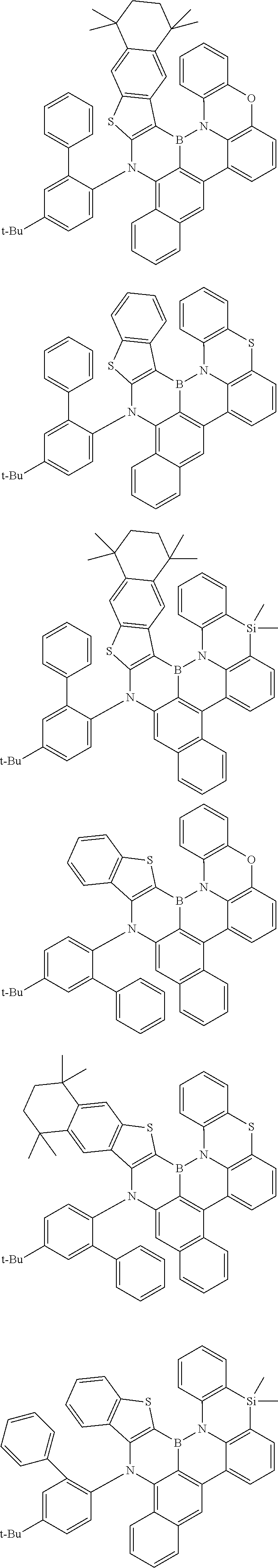 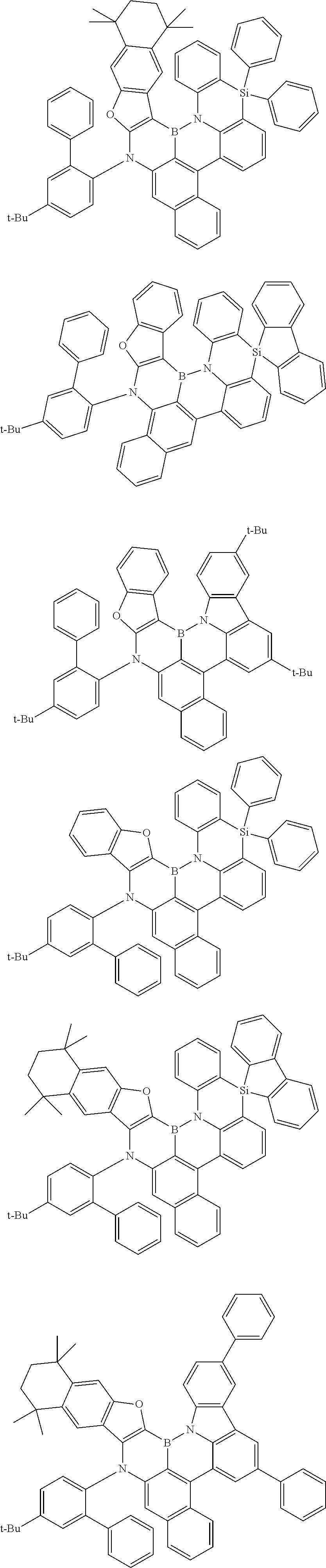 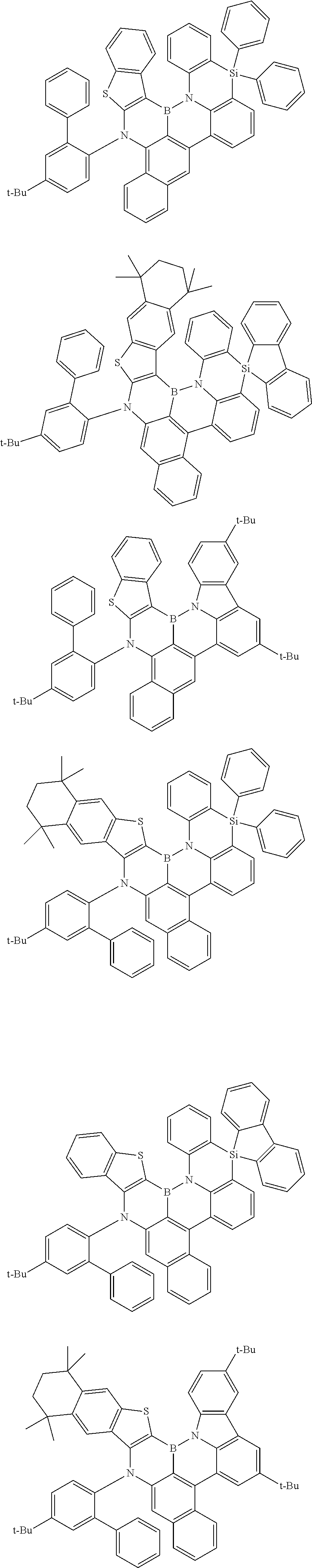 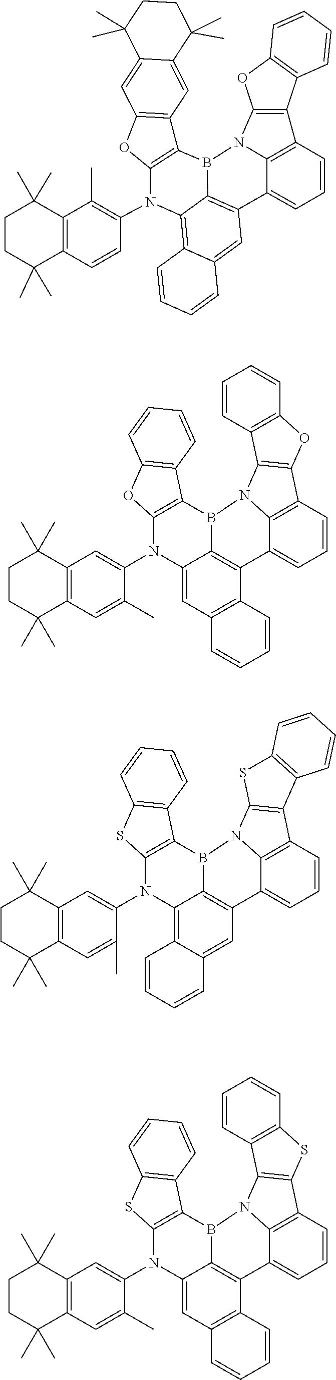 [SMILES: Cc1c(N2c3oc4cc5c(cc4c3B3c4c(cc6ccccc6c42)-c2cccc4c6c7ccccc7oc6n3c24)C(C)(C)CCC5(C)C)ccc2c1C(C)(C)CCC2(C)C ; Cc1cc2c(cc1N1c3cc4ccccc4c4c3B(c3c1oc1ccccc31)n1c3c-4cccc3c3oc4ccccc4c31)C(C)(C)CCC2(C)C ; Cc1cc2c(cc1N1c3sc4ccccc4c3B3c4c(cc5ccccc5c41)-c1cccc4c5c6ccccc6sc5n3c14)C(C)(C)CCC2(C)C ; Cc1cc2c(cc1N1c3cc4ccccc4c4c3B(c3c1sc1ccccc31)n1c3c-4cccc3c3sc4ccccc4c31)C(C)(C)CCC2(C)C] 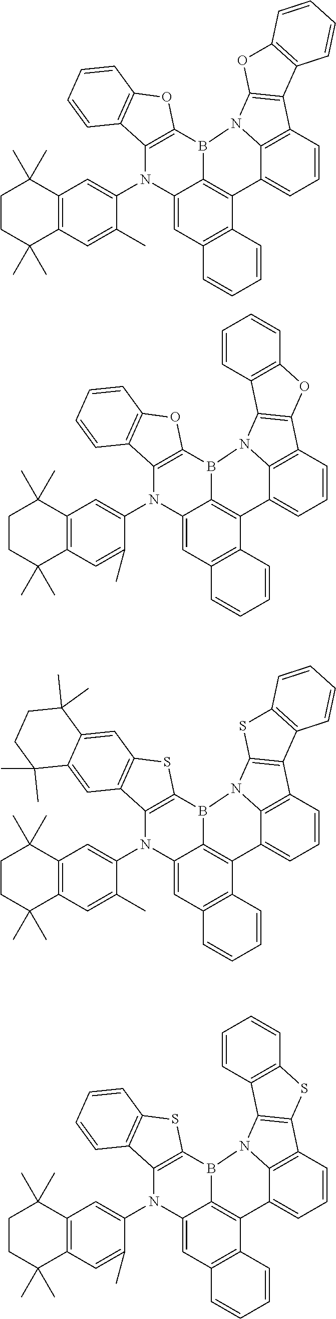 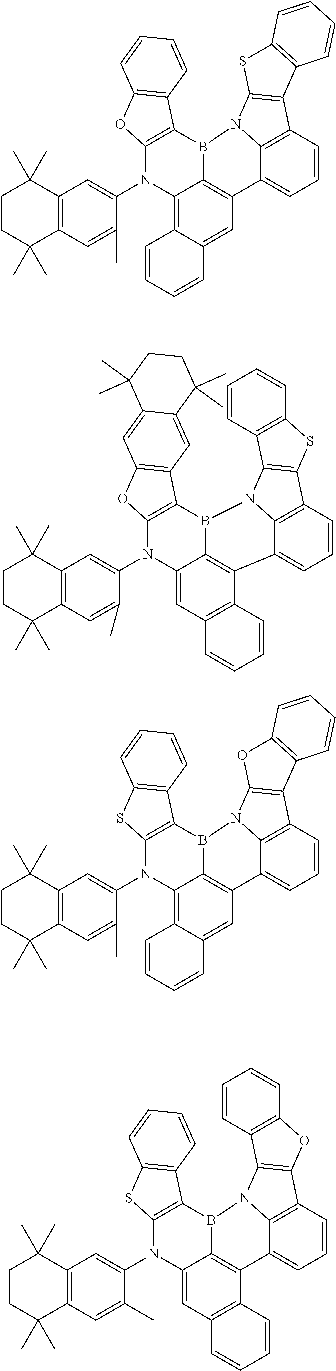 [SMILES: Cc1cc2c(cc1N1c3oc4ccccc4c3B3c4c(cc5ccccc5c41)-c1cccc4c5c6ccccc6sc5n3c14)C(C)(C)CCC2(C)C ; Cc1cc2c(cc1N1c3cc4ccccc4c4c3B(c3c1oc1cc5c(cc31)C(C)(C)CCC5(C)C)n1c3c-4cccc3c3sc4ccccc4c31)C(C)(C)CCC2(C)C ; Cc1cc2c(cc1N1c3sc4ccccc4c3B3c4c(cc5ccccc5c41)-c1cccc4c5c6ccccc6oc5n3c14)C(C)(C)CCC2(C)C ; Cc1cc2c(cc1N1c3cc4ccccc4c4c3B(c3c1sc1ccccc31)n1c3c-4cccc3c3oc4ccccc4c31)C(C)(C)CCC2(C)C] 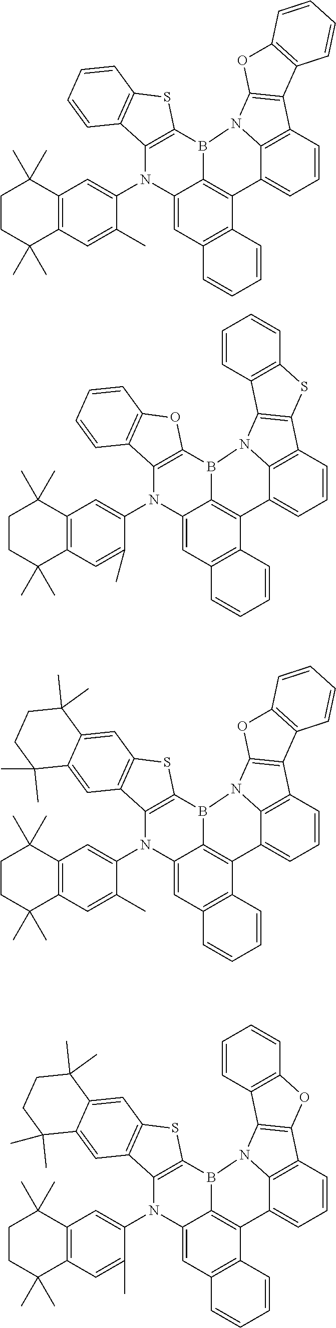 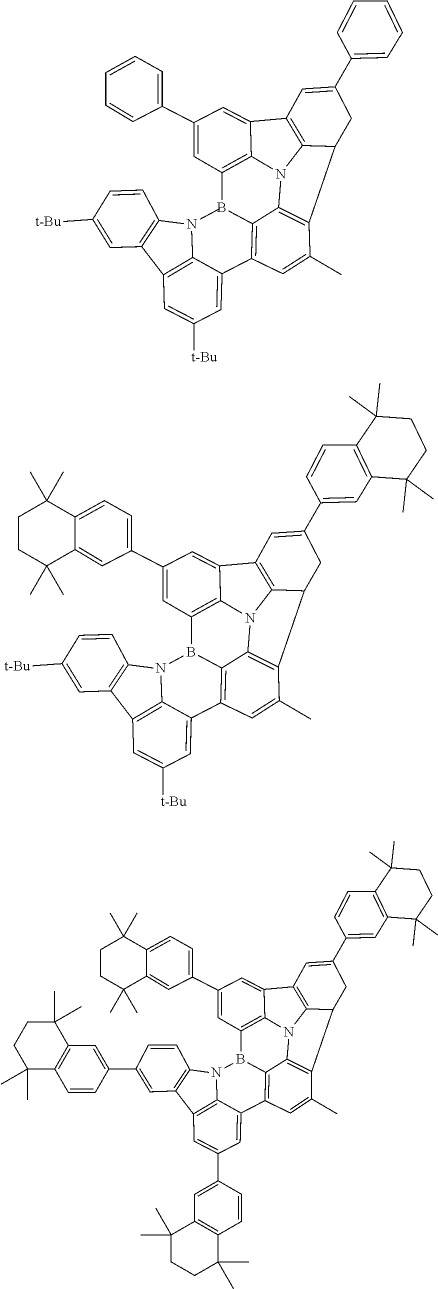 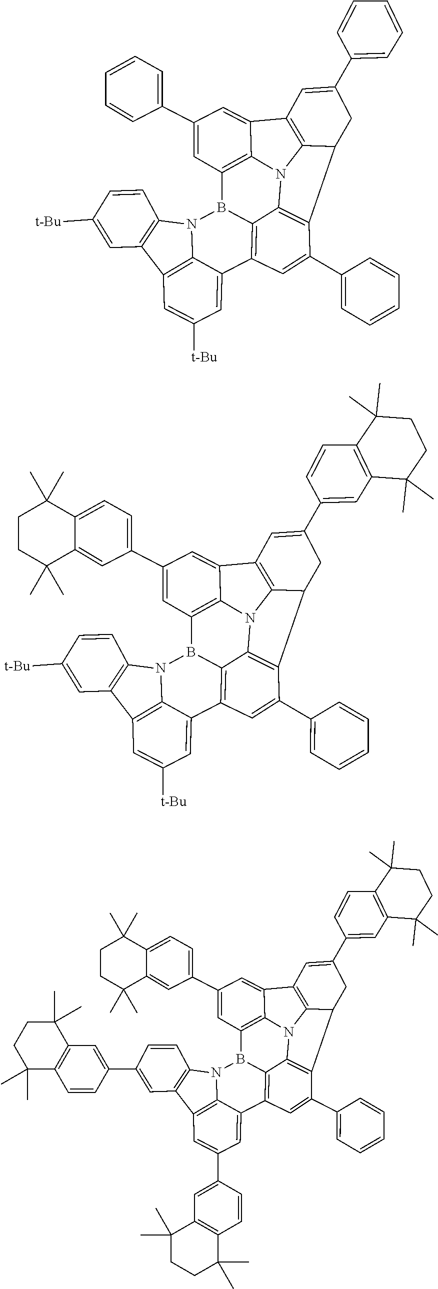 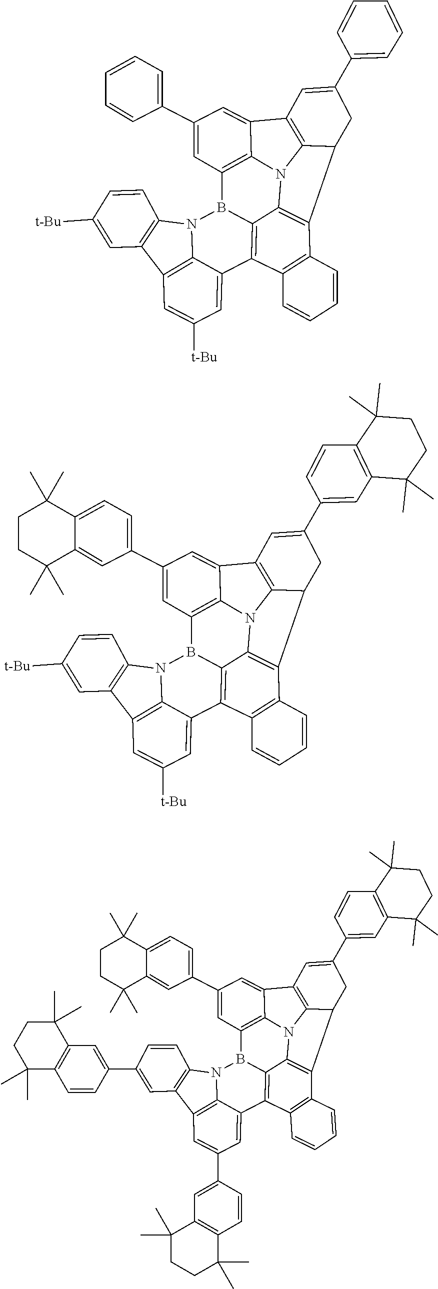 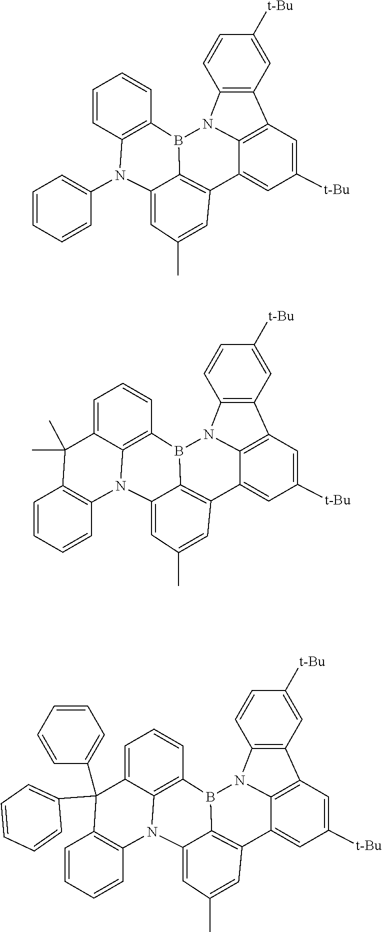 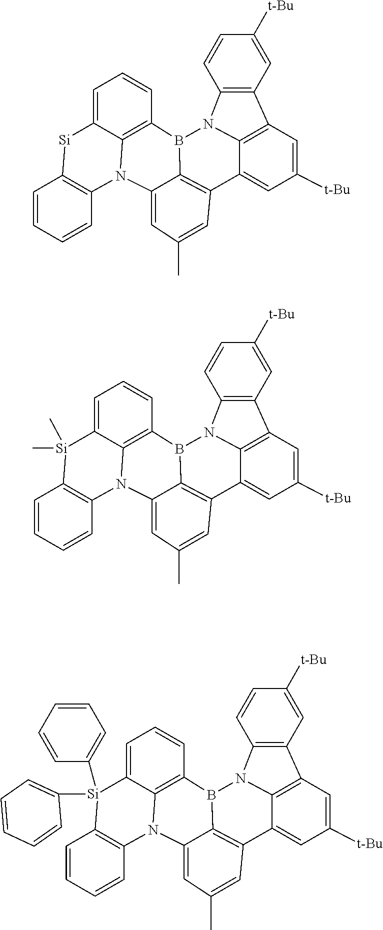 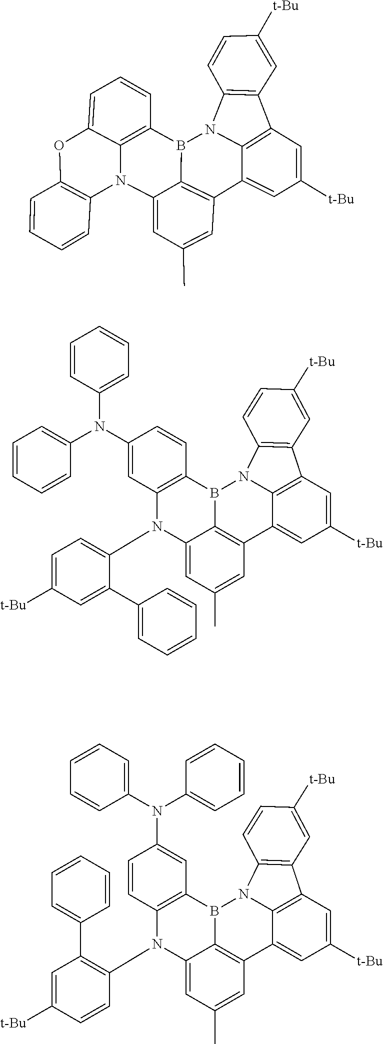 [SMILES: Cc1cc2c3c(c1)N1c4ccccc4Oc4cccc(c41)B3n1c3ccc(C(C)(C)C)cc3c3cc(C(C)(C)C)cc-2c31 ; Cc1cc2c3c(c1)N(c1ccc(C(C)(C)C)cc1-c1ccccc1)c1cc(N(c4ccccc4)c4ccccc4)ccc1B3n1c3ccc(C(C)(C)C)cc3c3cc(C(C)(C)C)cc-2c31 ; Cc1cc2c3c(c1)N(c1ccc(C(C)(C)C)cc1-c1ccccc1)c1ccc(N(c4ccccc4)c4ccccc4)cc1B3n1c3ccc(C(C)(C)C)cc3c3cc(C(C)(C)C)cc-2c31] 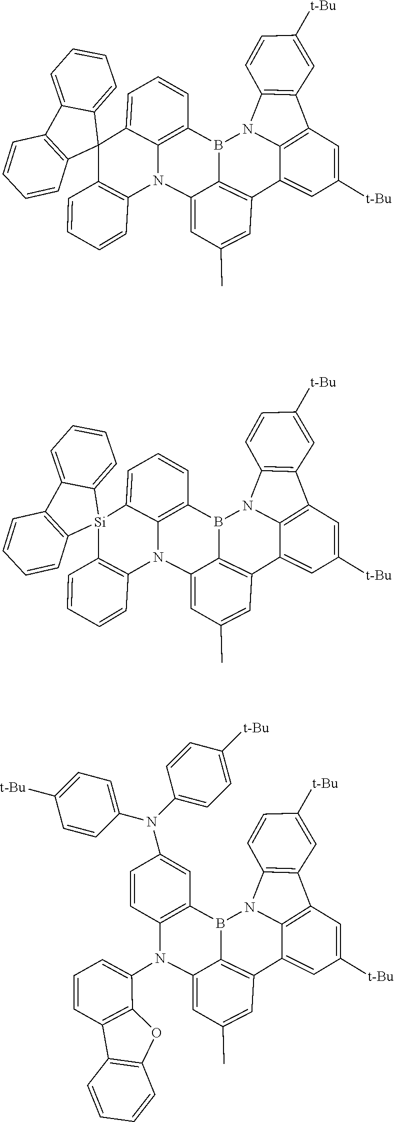 [SMILES: Cc1cc2c3c(c1)N1c4ccccc4C4(c5ccccc5-c5ccccc54)c4cccc(c41)B3n1c3ccc(C(C)(C)C)cc3c3cc(C(C)(C)C)cc-2c31 ; Cc1cc2c3c(c1)N1c4ccccc4[Si]4(c5ccccc5-c5ccccc54)c4cccc(c41)B3n1c3ccc(C(C)(C)C)cc3c3cc(C(C)(C)C)cc-2c31 ; Cc1cc2c3c(c1)N(c1cccc4c1oc1ccccc14)c1ccc(N(c4ccc(C(C)(C)C)cc4)c4ccc(C(C)(C)C)cc4)cc1B3n1c3ccc(C(C)(C)C)cc3c3cc(C(C)(C)C)cc-2c31] 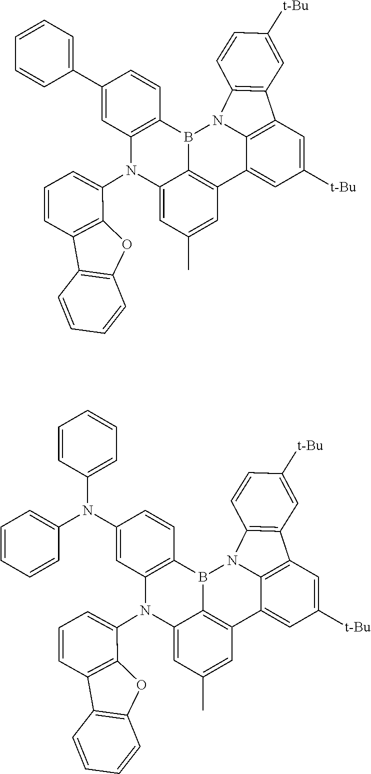 [SMILES: Cc1cc2c3c(c1)N(c1cccc4c1oc1ccccc14)c1cc(-c4ccccc4)ccc1B3n1c3ccc(C(C)(C)C)cc3c3cc(C(C)(C)C)cc-2c31 ; Cc1cc2c3c(c1)N(c1cccc4c1oc1ccccc14)c1cc(N(c4ccccc4)c4ccccc4)ccc1B3n1c3ccc(C(C)(C)C)cc3c3cc(C(C)(C)C)cc-2c31] 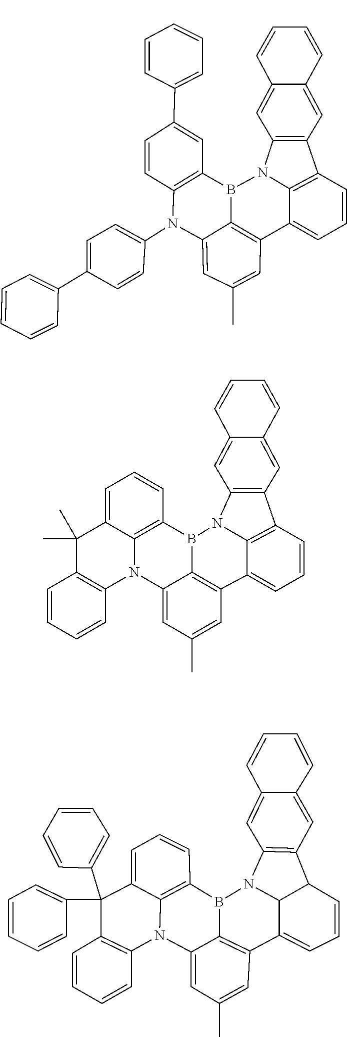 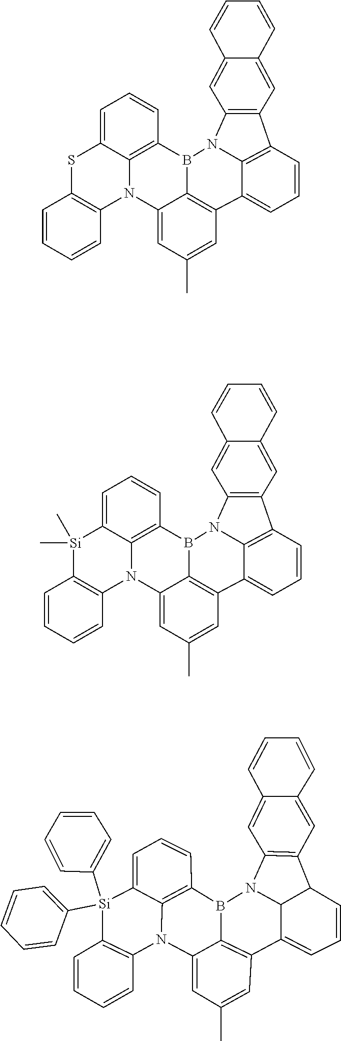 [SMILES: Cc1cc2c3c(c1)N1c4ccccc4Sc4cccc(c41)B3n1c3cc4ccccc4cc3c3cccc-2c31 ; Cc1cc2c3c(c1)N1c4ccccc4[Si](C)(C)c4cccc(c41)B3n1c3cc4ccccc4cc3c3cccc-2c31 ; Cc1cc2c3c(c1)N1c4ccccc4[Si](c4ccccc4)(c4ccccc4)c4cccc(c41)B3N1c3cc4ccccc4cc3C3C=CC=C2C31] 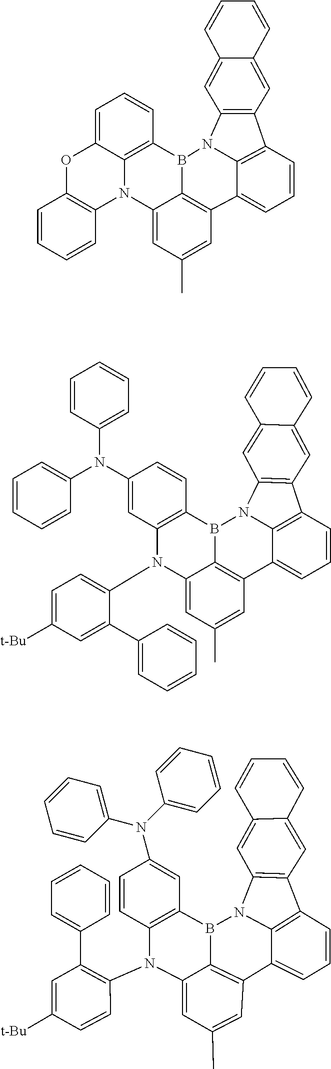 [SMILES: Cc1cc2c3c(c1)N1c4ccccc4Oc4cccc(c41)B3n1c3cc4ccccc4cc3c3cccc-2c31 ; Cc1cc2c3c(c1)N(c1ccc(C(C)(C)C)cc1-c1ccccc1)c1cc(N(c4ccccc4)c4ccccc4)ccc1B3n1c3cc4ccccc4cc3c3cccc-2c31 ; Cc1cc2c3c(c1)N(c1ccc(C(C)(C)C)cc1-c1ccccc1)c1ccc(N(c4ccccc4)c4ccccc4)cc1B3n1c3cc4ccccc4cc3c3cccc-2c31] 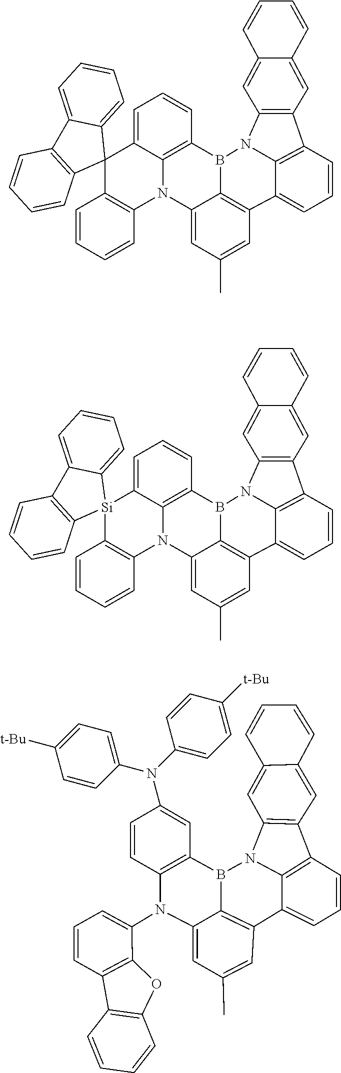 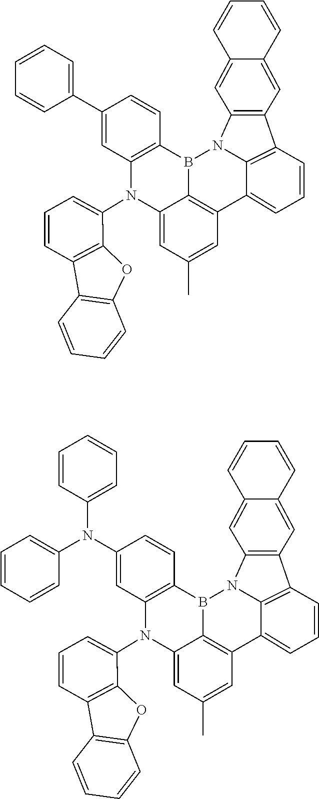 [SMILES: Cc1cc2c3c(c1)N(c1cccc4c1oc1ccccc14)c1cc(-c4ccccc4)ccc1B3n1c3cc4ccccc4cc3c3cccc-2c31 ; Cc1cc2c3c(c1)N(c1cccc4c1oc1ccccc14)c1cc(N(c4ccccc4)c4ccccc4)ccc1B3n1c3cc4ccccc4cc3c3cccc-2c31] 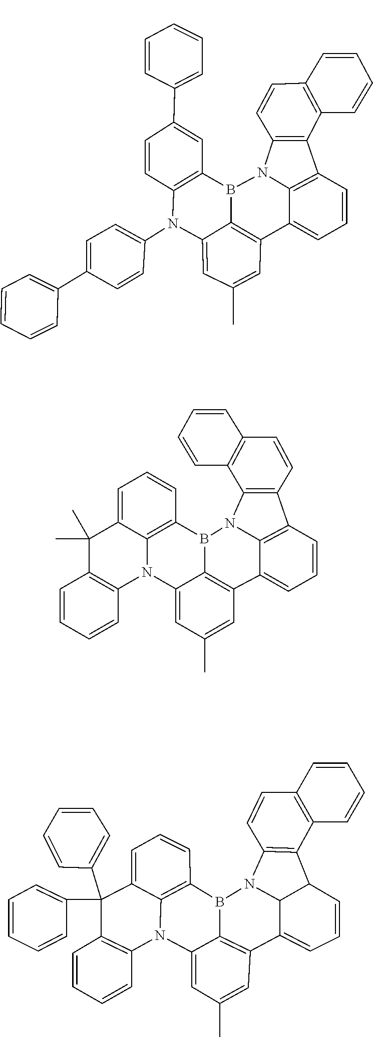 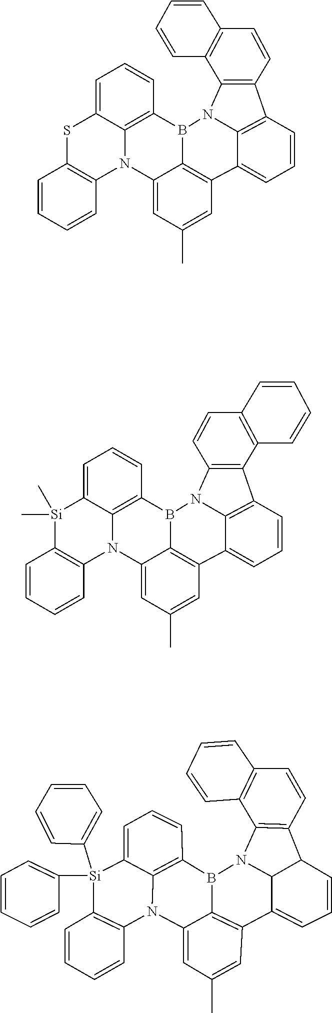 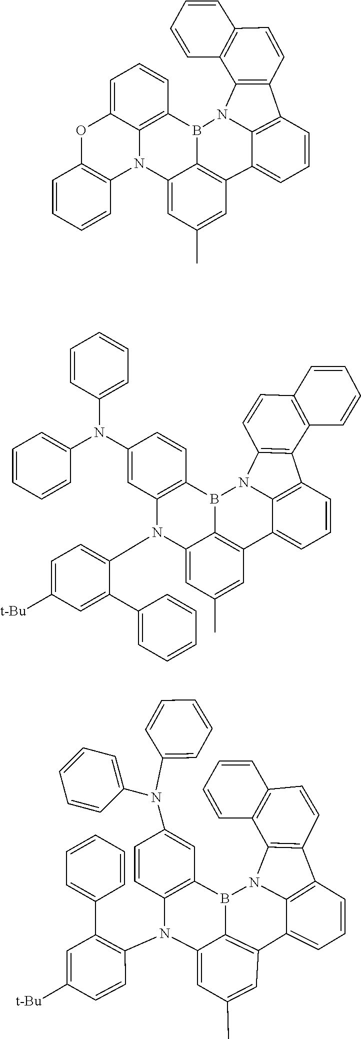 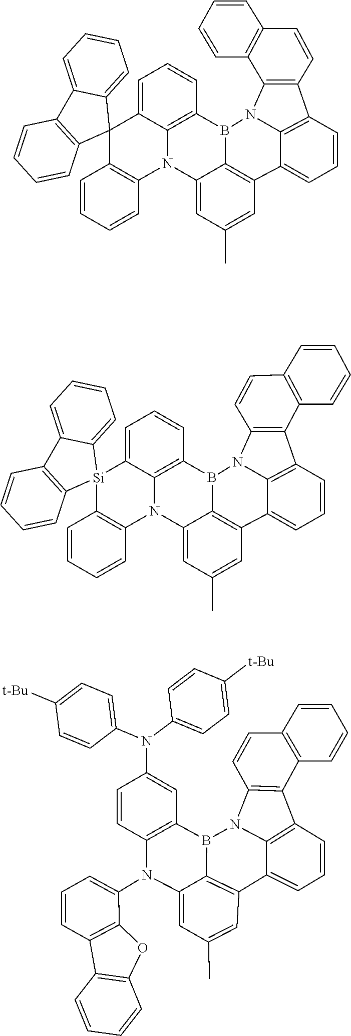 [SMILES: Cc1cc2c3c(c1)N1c4ccccc4C4(c5ccccc5-c5ccccc54)c4cccc(c41)B3n1c3c-2cccc3c2ccc3ccccc3c21 ; Cc1cc2c3c(c1)N1c4ccccc4[Si]4(c5ccccc5-c5ccccc54)c4cccc(c41)B3n1c3ccc4ccccc4c3c3cccc-2c31 ; Cc1cc2c3c(c1)N(c1cccc4c1oc1ccccc14)c1ccc(N(c4ccc(C(C)(C)C)cc4)c4ccc(C(C)(C)C)cc4)cc1B3n1c3ccc4ccccc4c3c3cccc-2c31] 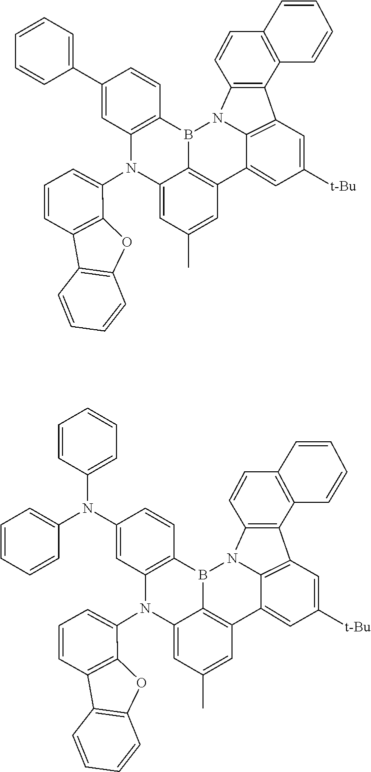 [SMILES: Cc1cc2c3c(c1)N(c1cccc4c1oc1ccccc14)c1cc(-c4ccccc4)ccc1B3n1c3ccc4ccccc4c3c3cc(C(C)(C)C)cc-2c31 ; Cc1cc2c3c(c1)N(c1cccc4c1oc1ccccc14)c1cc(N(c4ccccc4)c4ccccc4)ccc1B3n1c3ccc4ccccc4c3c3cc(C(C)(C)C)cc-2c31] 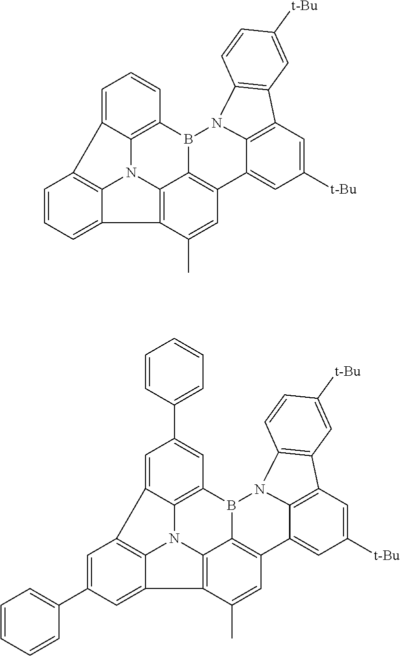 [SMILES: Cc1cc2c3c4c1c1cccc5c6cccc(c6n4c51)B3n1c3ccc(C(C)(C)C)cc3c3cc(C(C)(C)C)cc-2c31 ; Cc1cc2c3c4c1c1cc(-c5ccccc5)cc5c6cc(-c7ccccc7)cc(c6n4c51)B3n1c3ccc(C(C)(C)C)cc3c3cc(C(C)(C)C)cc-2c31] 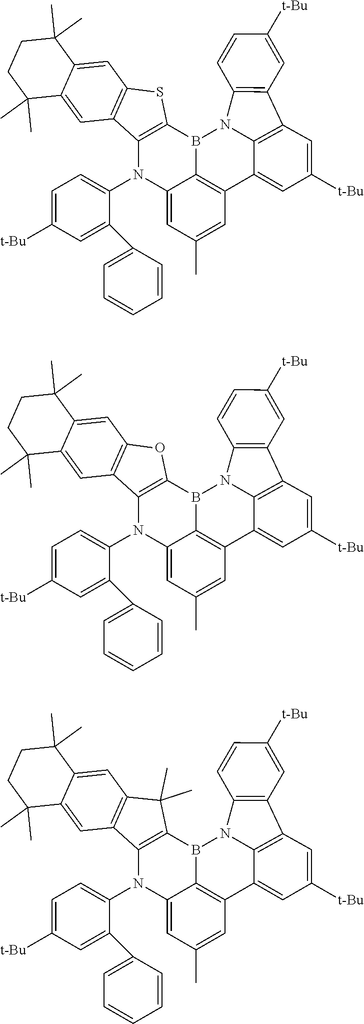 [SMILES: Cc1cc2c3c(c1)N(c1ccc(C(C)(C)C)cc1-c1ccccc1)c1c(sc4cc5c(cc14)C(C)(C)CCC5(C)C)B3n1c3ccc(C(C)(C)C)cc3c3cc(C(C)(C)C)cc-2c31 ; Cc1cc2c3c(c1)N(c1ccc(C(C)(C)C)cc1-c1ccccc1)c1c(oc4cc5c(cc14)C(C)(C)CCC5(C)C)B3n1c3ccc(C(C)(C)C)cc3c3cc(C(C)(C)C)cc-2c31 ; Cc1cc2c3c(c1)N(c1ccc(C(C)(C)C)cc1-c1ccccc1)C1=C(B3n3c4ccc(C(C)(C)C)cc4c4cc(C(C)(C)C)cc-2c43)C(C)(C)c2cc3c(cc21)C(C)(C)CCC3(C)C] 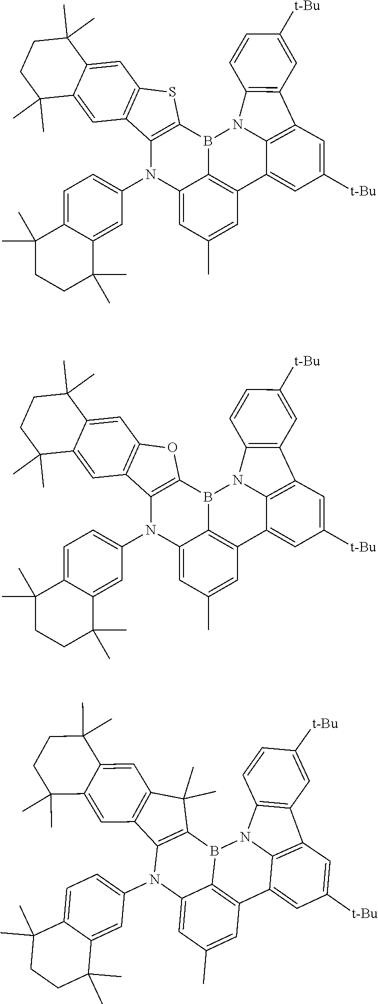 [SMILES: Cc1cc2c3c(c1)N(c1ccc4c(c1)C(C)(C)CCC4(C)C)c1c(sc4cc5c(cc14)C(C)(C)CCC5(C)C)B3n1c3ccc(C(C)(C)C)cc3c3cc(C(C)(C)C)cc-2c31 ; Cc1cc2c3c(c1)N(c1ccc4c(c1)C(C)(C)CCC4(C)C)c1c(oc4cc5c(cc14)C(C)(C)CCC5(C)C)B3n1c3ccc(C(C)(C)C)cc3c3cc(C(C)(C)C)cc-2c31 ; Cc1cc2c3c(c1)N(c1ccc4c(c1)C(C)(C)CCC4(C)C)C1=C(B3n3c4ccc(C(C)(C)C)cc4c4cc(C(C)(C)C)cc-2c43)C(C)(C)c2cc3c(cc21)C(C)(C)CCC3(C)C] 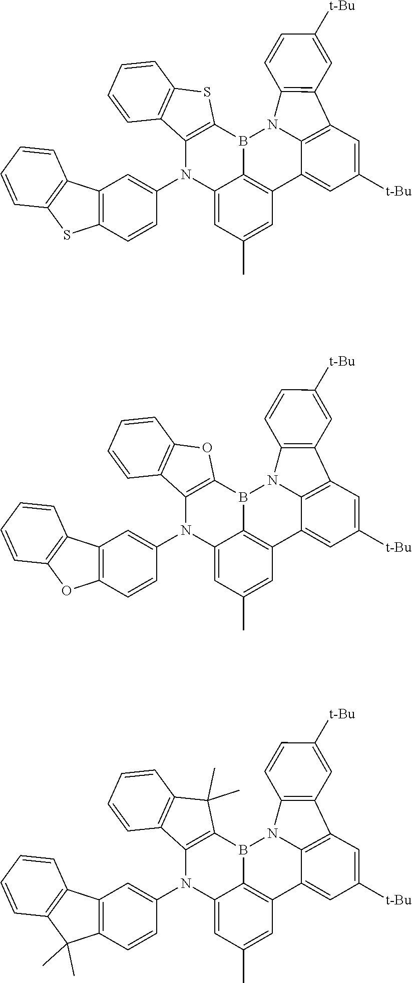 [SMILES: Cc1cc2c3c(c1)N(c1ccc4sc5ccccc5c4c1)c1c(sc4ccccc14)B3n1c3ccc(C(C)(C)C)cc3c3cc(C(C)(C)C)cc-2c31 ; Cc1cc2c3c(c1)N(c1ccc4oc5ccccc5c4c1)c1c(oc4ccccc14)B3n1c3ccc(C(C)(C)C)cc3c3cc(C(C)(C)C)cc-2c31 ; Cc1cc2c3c(c1)N(c1ccc4c(c1)-c1ccccc1C4(C)C)C1=C(B3n3c4ccc(C(C)(C)C)cc4c4cc(C(C)(C)C)cc-2c43)C(C)(C)c2ccccc21] 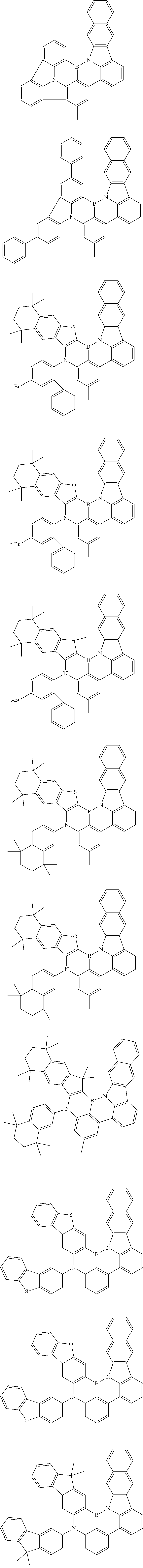 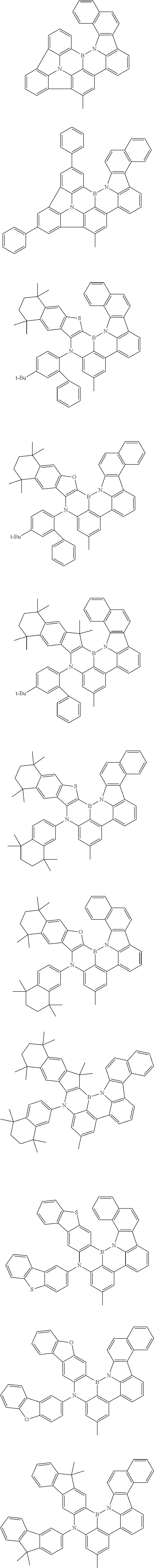 [chemical structure] [chemical structure] [chemical structure] 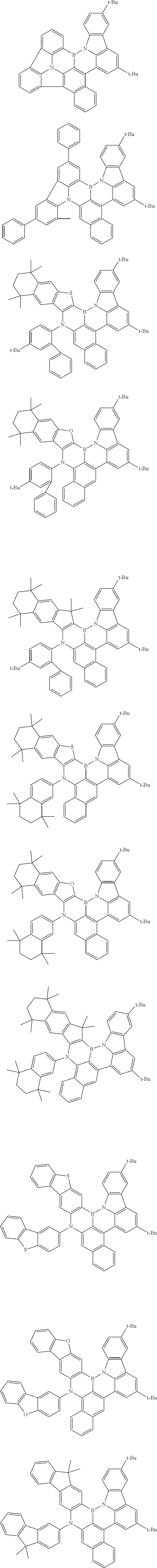 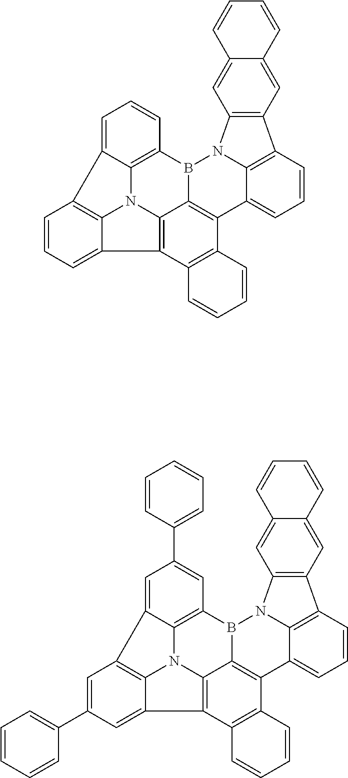 [SMILES: c1ccc2cc3c(cc2c1)c1cccc2c1n3B1c3cccc4c5cccc6c7c8ccccc8c-2c1c7n(c34)c56 ; c1ccc(-c2cc3c4c(c2)c2cc(-c5ccccc5)cc5c6c7ccccc7c7c(c6n4c25)B3n2c3cc4ccccc4cc3c3cccc-7c32)cc1] 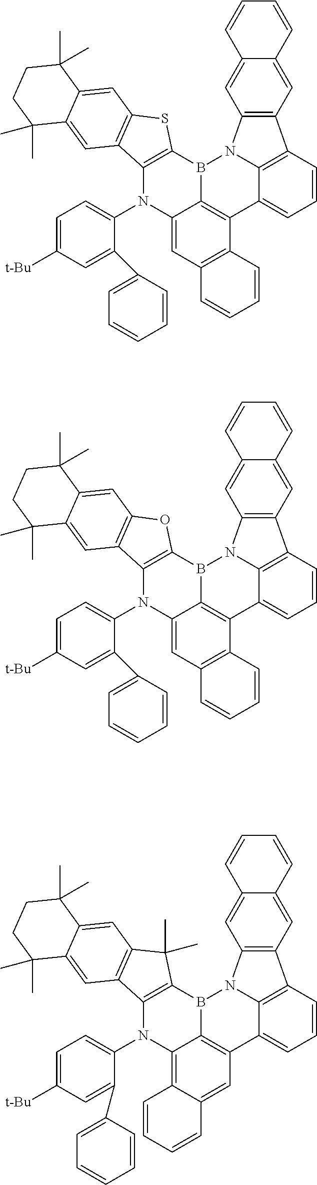 [SMILES: CC(C)(C)c1ccc(N2c3cc4ccccc4c4c3B(c3sc5cc6c(cc5c32)C(C)(C)CCC6(C)C)n2c3cc5ccccc5cc3c3cccc-4c32)c(-c2ccccc2)c1 ; CC(C)(C)c1ccc(N2c3cc4ccccc4c4c3B(c3oc5cc6c(cc5c32)C(C)(C)CCC6(C)C)n2c3cc5ccccc5cc3c3cccc-4c32)c(-c2ccccc2)c1 ; CC(C)(C)c1ccc(N2C3=C(B4c5c(cc6ccccc6c52)-c2cccc5c6cc7ccccc7cc6n4c25)C(C)(C)c2cc4c(cc23)C(C)(C)CCC4(C)C)c(-c2ccccc2)c1] 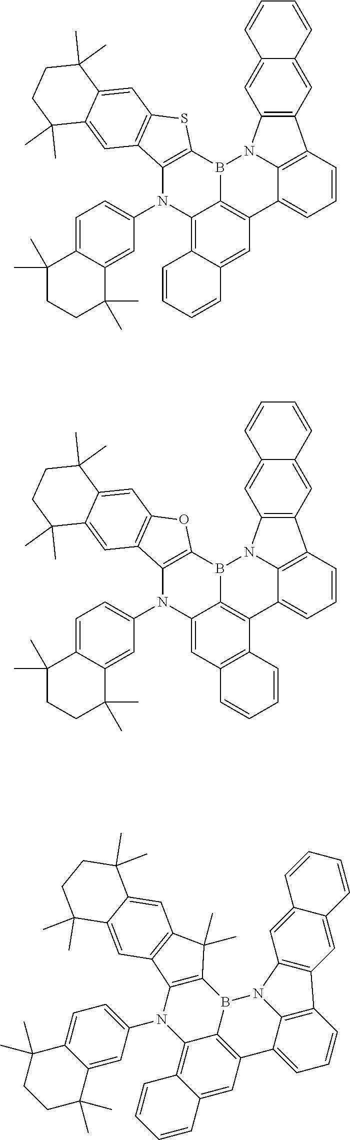 [SMILES: CC1(C)CCC(C)(C)c2cc(N3c4c5c(cc6ccccc46)-c4cccc6c7cc8ccccc8cc7n(c46)B5c4sc5cc6c(cc5c43)C(C)(C)CCC6(C)C)ccc21 ; CC1(C)CCC(C)(C)c2cc(N3c4cc5ccccc5c5c4B(c4oc6cc7c(cc6c43)C(C)(C)CCC7(C)C)n3c4cc6ccccc6cc4c4cccc-5c43)ccc21 ; CC1(C)CCC(C)(C)c2cc(N3C4=C(B5c6c(cc7ccccc7c63)-c3cccc6c7cc8ccccc8cc7n5c36)C(C)(C)c3cc5c(cc34)C(C)(C)CCC5(C)C)ccc21] 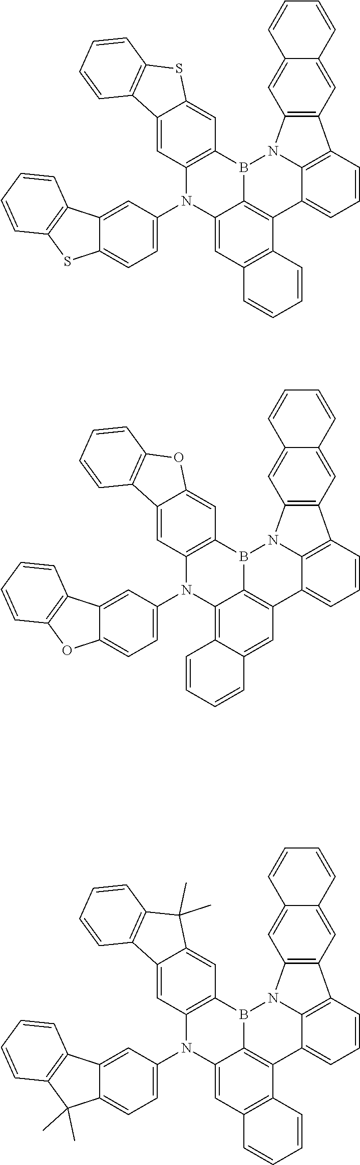 [SMILES: c1ccc2cc3c(cc2c1)c1cccc2c1n3B1c3cc4sc5ccccc5c4cc3N(c3ccc4sc5ccccc5c4c3)c3cc4ccccc4c-2c31 ; c1ccc2cc3c(cc2c1)c1cccc2c1n3B1c3cc4oc5ccccc5c4cc3N(c3ccc4oc5ccccc5c4c3)c3c1c-2cc1ccccc31 ; CC1(C)c2ccccc2-c2cc(N3c4cc5c(cc4B4c6c3cc3ccccc3c6-c3cccc6c7cc8ccccc8cc7n4c36)C(C)(C)c3ccccc3-5)ccc21] 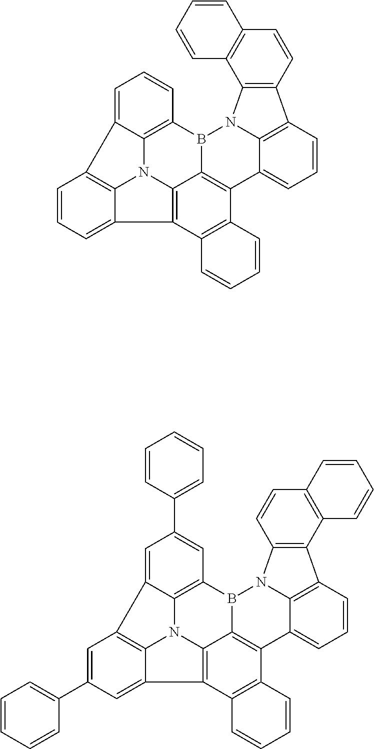 [SMILES: c1ccc2c(c1)ccc1c3cccc4c3n(c21)B1c2cccc3c5cccc6c7c8ccccc8c-4c1c7n(c23)c56 ; c1ccc(-c2cc3c4c(c2)c2cc(-c5ccccc5)cc5c6c7ccccc7c7c(c6n4c25)B3n2c3ccc4ccccc4c3c3cccc-7c32)cc1] 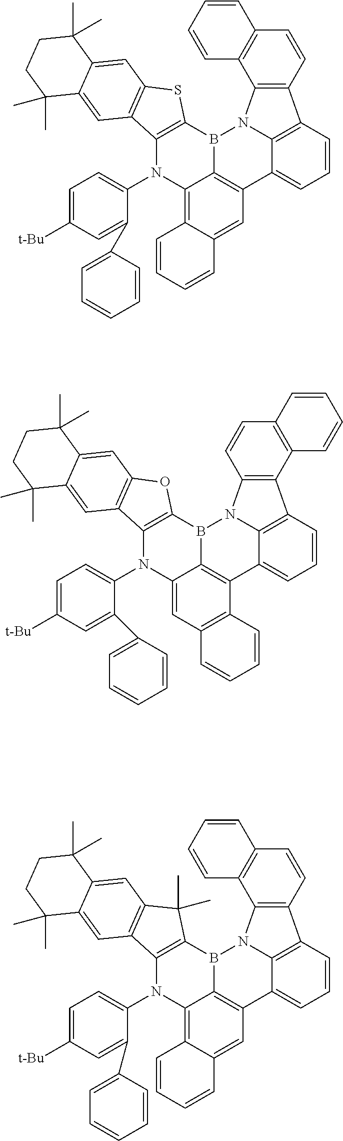 [SMILES: CC(C)(C)c1ccc(N2c3c4c(cc5ccccc35)-c3cccc5c6ccc7ccccc7c6n(c35)B4c3sc4cc5c(cc4c32)C(C)(C)CCC5(C)C)c(-c2ccccc2)c1 ; CC(C)(C)c1ccc(N2c3cc4ccccc4c4c3B(c3oc5cc6c(cc5c32)C(C)(C)CCC6(C)C)n2c3ccc5ccccc5c3c3cccc-4c32)c(-c2ccccc2)c1 ; CC(C)(C)c1ccc(N2C3=C(B4c5c(cc6ccccc6c52)-c2cccc5c6ccc7ccccc7c6n4c25)C(C)(C)c2cc4c(cc23)C(C)(C)CCC4(C)C)c(-c2ccccc2)c1] 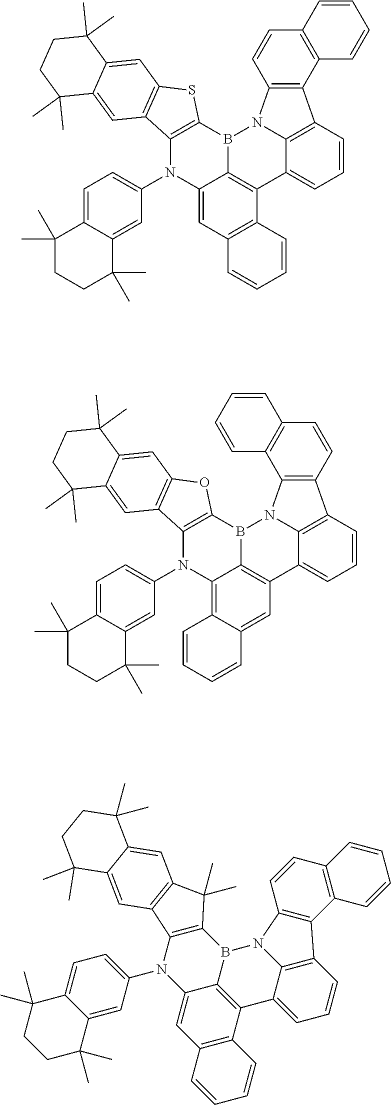 [SMILES: CC1(C)CCC(C)(C)c2cc(N3c4cc5ccccc5c5c4B(c4sc6cc7c(cc6c43)C(C)(C)CCC7(C)C)n3c4ccc6ccccc6c4c4cccc-5c43)ccc21 ; CC1(C)CCC(C)(C)c2cc(N3c4c5c(cc6ccccc46)-c4cccc6c7ccc8ccccc8c7n(c46)B5c4oc5cc6c(cc5c43)C(C)(C)CCC6(C)C)ccc21 ; CC1(C)CCC(C)(C)c2cc(N3C4=C(B5c6c3cc3ccccc3c6-c3cccc6c7c8ccccc8ccc7n5c36)C(C)(C)c3cc5c(cc34)C(C)(C)CCC5(C)C)ccc21] 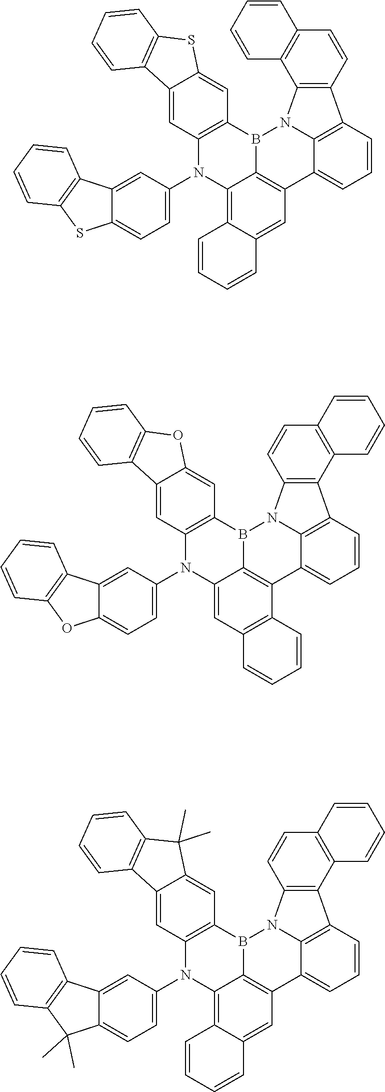 [SMILES: c1ccc2c3c4c(cc2c1)-c1cccc2c5ccc6ccccc6c5n(c12)B4c1cc2sc4ccccc4c2cc1N3c1ccc2sc3ccccc3c2c1 ; c1ccc2c3c4c(cc2c1)N(c1ccc2oc5ccccc5c2c1)c1cc2c(cc1B4n1c4ccc5ccccc5c4c4cccc-3c41)oc1ccccc12 ; CC1(C)c2ccccc2-c2cc(N3c4cc5c(cc4B4c6c(cc7ccccc7c63)-c3cccc6c7c8ccccc8ccc7n4c36)C(C)(C)c3ccccc3-5)ccc21] 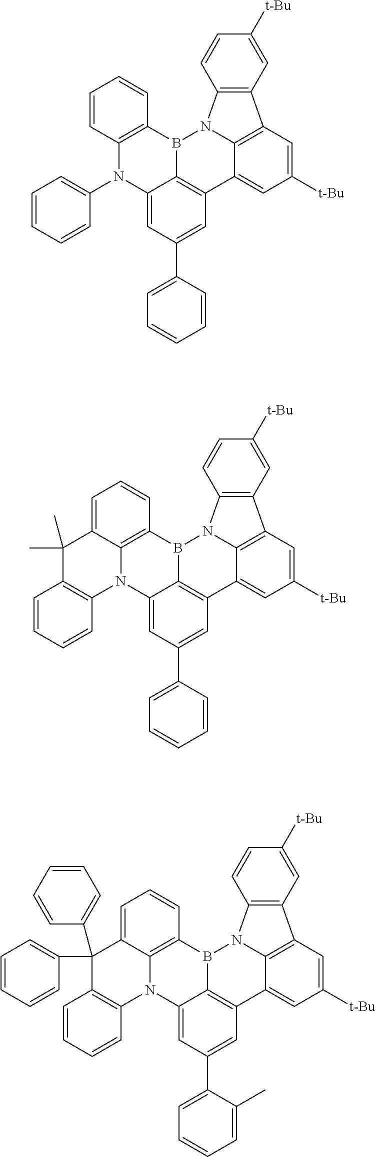 [SMILES: CC(C)(C)c1ccc2c(c1)c1cc(C(C)(C)C)cc3c1n2B1c2ccccc2N(c2ccccc2)c2cc(-c4ccccc4)cc-3c21 ; CC(C)(C)c1ccc2c(c1)c1cc(C(C)(C)C)cc3c1n2B1c2cccc4c2N(c2ccccc2C4(C)C)c2cc(-c4ccccc4)cc-3c21 ; Cc1ccccc1-c1cc2c3c(c1)N1c4ccccc4C(c4ccccc4)(c4ccccc4)c4cccc(c41)B3n1c3ccc(C(C)(C)C)cc3c3cc(C(C)(C)C)cc-2c31] 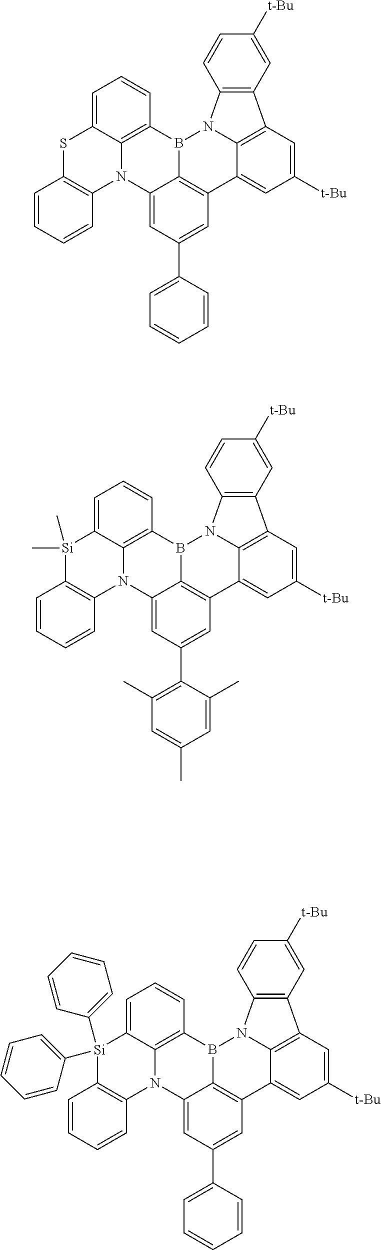 [SMILES: CC(C)(C)c1ccc2c(c1)c1cc(C(C)(C)C)cc3c1n2B1c2cccc4c2N(c2ccccc2S4)c2cc(-c4ccccc4)cc-3c21 ; Cc1cc(C)c(-c2cc3c4c(c2)N2c5ccccc5[Si](C)(C)c5cccc(c52)B4n2c4ccc(C(C)(C)C)cc4c4cc(C(C)(C)C)cc-3c42)c(C)c1 ; CC(C)(C)c1ccc2c(c1)c1cc(C(C)(C)C)cc3c1n2B1c2cccc4c2N(c2ccccc2[Si]4(c2ccccc2)c2ccccc2)c2cc(-c4ccccc4)cc-3c21] 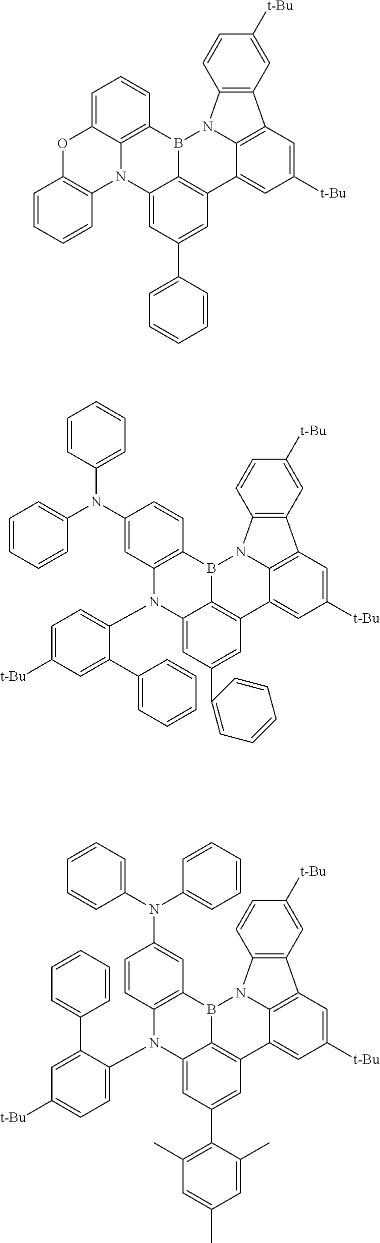 [SMILES: CC(C)(C)c1ccc2c(c1)c1cc(C(C)(C)C)cc3c1n2B1c2cccc4c2N(c2ccccc2O4)c2cc(-c4ccccc4)cc-3c21 ; CC(C)(C)c1ccc(N2c3cc(N(c4ccccc4)c4ccccc4)ccc3B3c4c(cc(-c5ccccc5)cc42)-c2cc(C(C)(C)C)cc4c5cc(C(C)(C)C)ccc5n3c24)c(-c2ccccc2)c1 ; Cc1cc(C)c(-c2cc3c4c(c2)N(c2ccc(C(C)(C)C)cc2-c2ccccc2)c2ccc(N(c5ccccc5)c5ccccc5)cc2B4n2c4ccc(C(C)(C)C)cc4c4cc(C(C)(C)C)cc-3c42)c(C)c1] 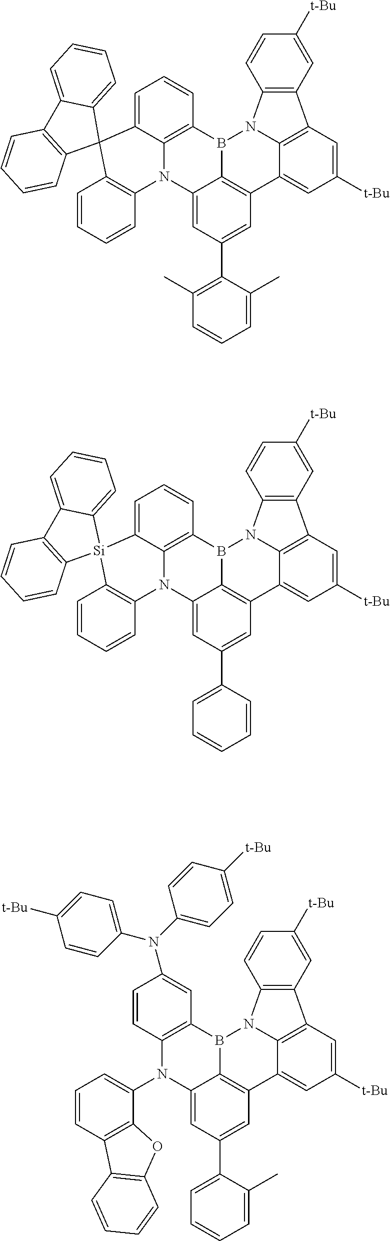 [SMILES: Cc1cccc(C)c1-c1cc2c3c(c1)N1c4ccccc4C4(c5ccccc5-c5ccccc54)c4cccc(c41)B3n1c3ccc(C(C)(C)C)cc3c3cc(C(C)(C)C)cc-2c31 ; CC(C)(C)c1ccc2c(c1)c1cc(C(C)(C)C)cc3c1n2B1c2cccc4c2N(c2ccccc2[Si]42c4ccccc4-c4ccccc42)c2cc(-c4ccccc4)cc-3c21 ; Cc1ccccc1-c1cc2c3c(c1)N(c1cccc4c1oc1ccccc14)c1ccc(N(c4ccc(C(C)(C)C)cc4)c4ccc(C(C)(C)C)cc4)cc1B3n1c3ccc(C(C)(C)C)cc3c3cc(C(C)(C)C)cc-2c31] 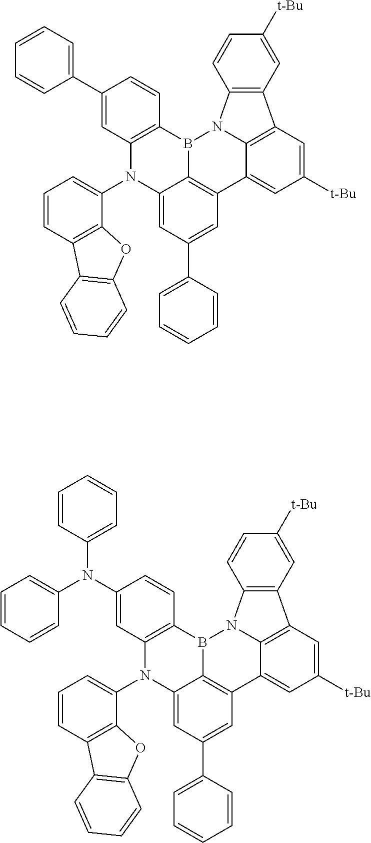 [SMILES: CC(C)(C)c1ccc2c(c1)c1cc(C(C)(C)C)cc3c1n2B1c2ccc(-c4ccccc4)cc2N(c2cccc4c2oc2ccccc24)c2cc(-c4ccccc4)cc-3c21 ; CC(C)(C)c1ccc2c(c1)c1cc(C(C)(C)C)cc3c1n2B1c2ccc(N(c4ccccc4)c4ccccc4)cc2N(c2cccc4c2oc2ccccc24)c2cc(-c4ccccc4)cc-3c21] 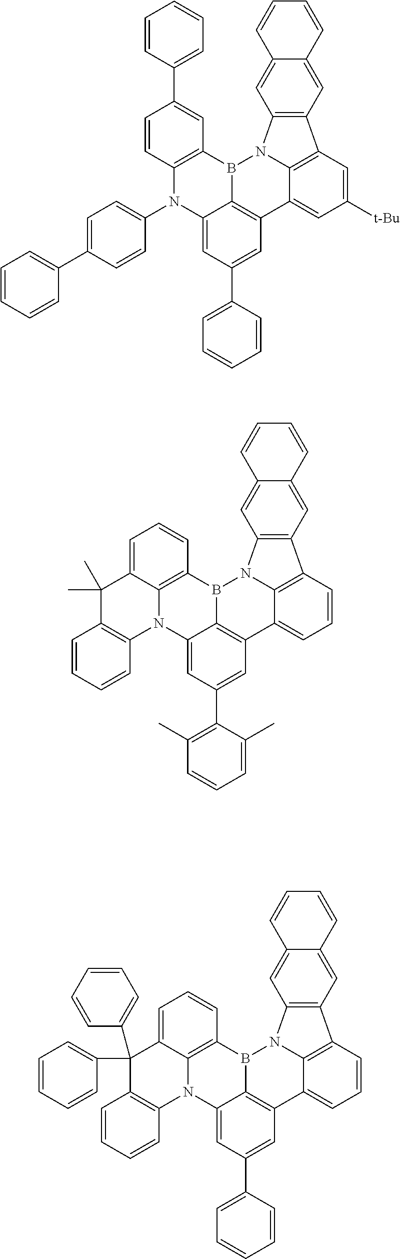 [SMILES: CC(C)(C)c1cc2c3c(c1)c1cc4ccccc4cc1n3B1c3cc(-c4ccccc4)ccc3N(c3ccc(-c4ccccc4)cc3)c3cc(-c4ccccc4)cc-2c31 ; Cc1cccc(C)c1-c1cc2c3c(c1)N1c4ccccc4C(C)(C)c4cccc(c41)B3n1c3cc4ccccc4cc3c3cccc-2c31 ; c1ccc(-c2cc3c4c(c2)N2c5ccccc5C(c5ccccc5)(c5ccccc5)c5cccc(c52)B4n2c4cc5ccccc5cc4c4cccc-3c42)cc1] 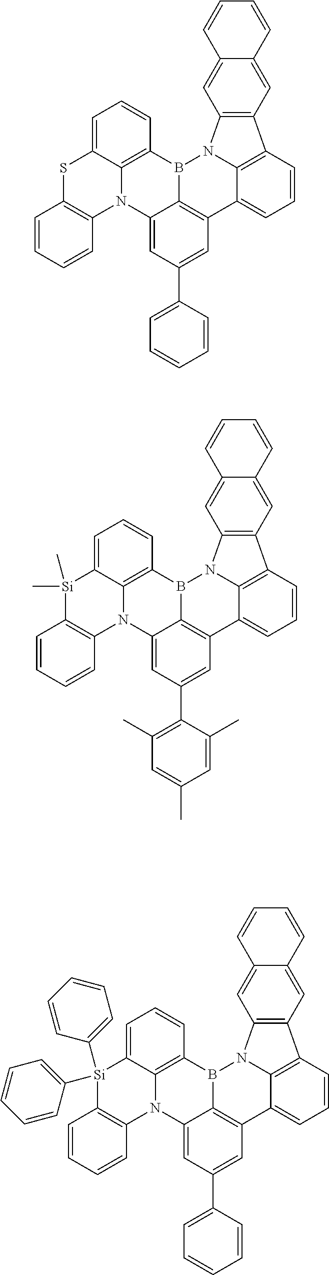 [SMILES: c1ccc(-c2cc3c4c(c2)N2c5ccccc5Sc5cccc(c52)B4n2c4cc5ccccc5cc4c4cccc-3c42)cc1 ; Cc1cc(C)c(-c2cc3c4c(c2)N2c5ccccc5[Si](C)(C)c5cccc(c52)B4n2c4cc5ccccc5cc4c4cccc-3c42)c(C)c1 ; c1ccc(-c2cc3c4c(c2)N2c5ccccc5[Si](c5ccccc5)(c5ccccc5)c5cccc(c52)B4n2c4cc5ccccc5cc4c4cccc-3c42)cc1] 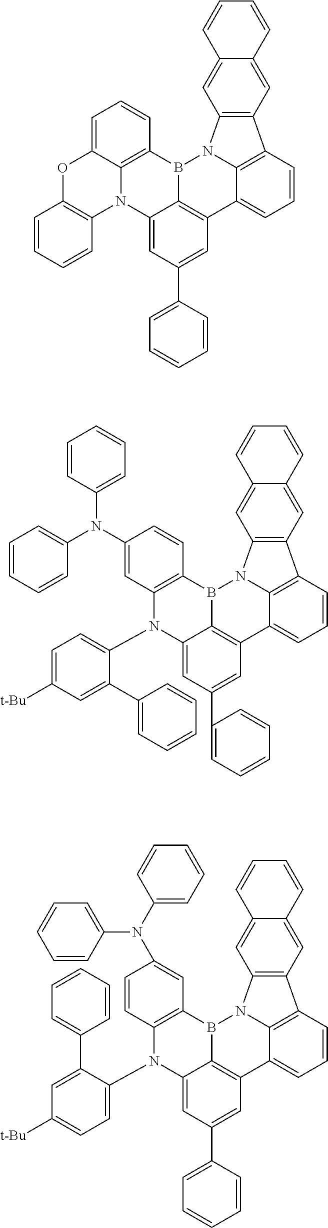 [SMILES: c1ccc(-c2cc3c4c(c2)N2c5ccccc5Oc5cccc(c52)B4n2c4cc5ccccc5cc4c4cccc-3c42)cc1 ; CC(C)(C)c1ccc(N2c3cc(N(c4ccccc4)c4ccccc4)ccc3B3c4c(cc(-c5ccccc5)cc42)-c2cccc4c5cc6ccccc6cc5n3c24)c(-c2ccccc2)c1 ; CC(C)(C)c1ccc(N2c3ccc(N(c4ccccc4)c4ccccc4)cc3B3c4c(cc(-c5ccccc5)cc42)-c2cccc4c5cc6ccccc6cc5n3c24)c(-c2ccccc2)c1] 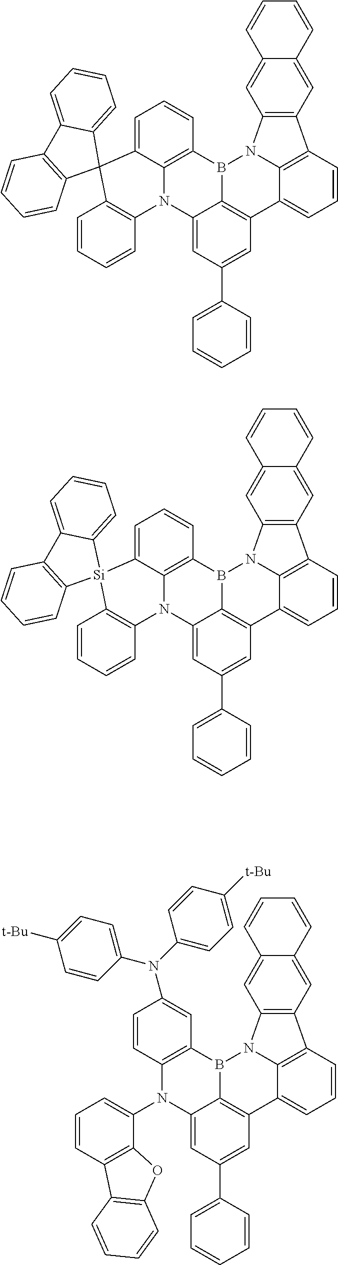 [SMILES: c1ccc(-c2cc3c4c(c2)N2c5ccccc5C5(c6ccccc6-c6ccccc65)c5cccc(c52)B4n2c4cc5ccccc5cc4c4cccc-3c42)cc1 ; c1ccc(-c2cc3c4c(c2)N2c5ccccc5[Si]5(c6ccccc6-c6ccccc65)c5cccc(c52)B4n2c4cc5ccccc5cc4c4cccc-3c42)cc1 ; CC(C)(C)c1ccc(N(c2ccc(C(C)(C)C)cc2)c2ccc3c(c2)B2c4c(cc(-c5ccccc5)cc4N3c3cccc4c3oc3ccccc34)-c3cccc4c5cc6ccccc6cc5n2c34)cc1] 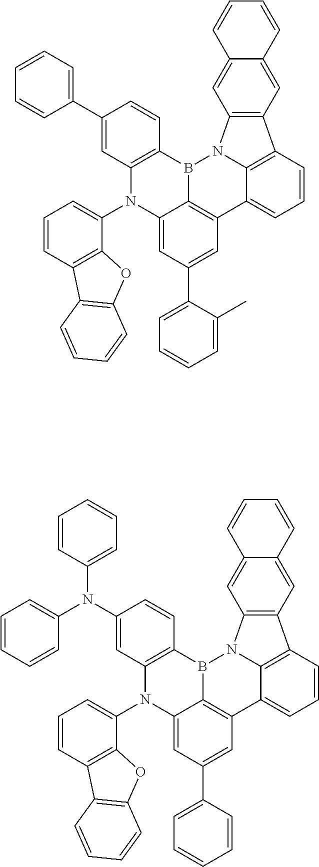 [SMILES: Cc1ccccc1-c1cc2c3c(c1)N(c1cccc4c1oc1ccccc14)c1cc(-c4ccccc4)ccc1B3n1c3cc4ccccc4cc3c3cccc-2c31 ; c1ccc(-c2cc3c4c(c2)N(c2cccc5c2oc2ccccc25)c2cc(N(c5ccccc5)c5ccccc5)ccc2B4n2c4cc5ccccc5cc4c4cccc-3c42)cc1] 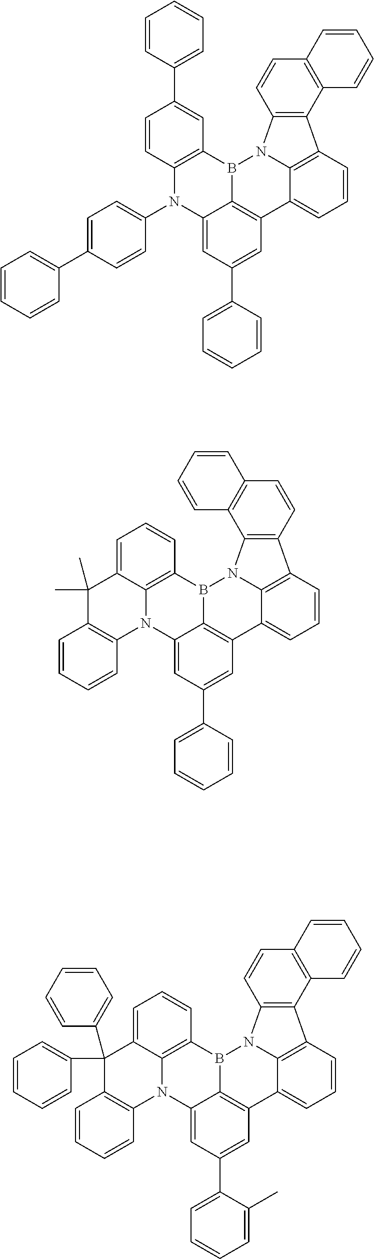 [SMILES: c1ccc(-c2ccc(N3c4ccc(-c5ccccc5)cc4B4c5c(cc(-c6ccccc6)cc53)-c3cccc5c6c7ccccc7ccc6n4c35)cc2)cc1 ; CC1(C)c2ccccc2N2c3cc(-c4ccccc4)cc4c3B(c3cccc1c32)n1c2c-4cccc2c2ccc3ccccc3c21 ; Cc1ccccc1-c1cc2c3c(c1)N1c4ccccc4C(c4ccccc4)(c4ccccc4)c4cccc(c41)B3n1c3ccc4ccccc4c3c3cccc-2c31] 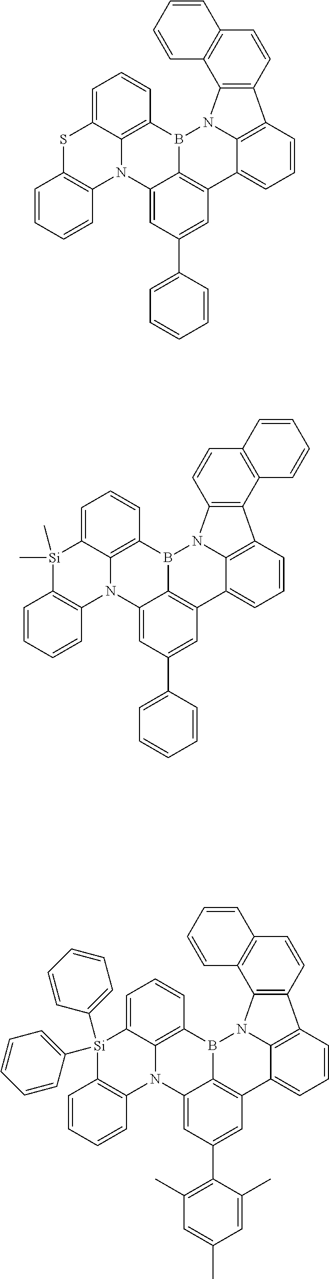 [SMILES: c1ccc(-c2cc3c4c(c2)N2c5ccccc5Sc5cccc(c52)B4n2c4c-3cccc4c3ccc4ccccc4c32)cc1 ; C[Si]1(C)c2ccccc2N2c3cc(-c4ccccc4)cc4c3B(c3cccc1c32)n1c2ccc3ccccc3c2c2cccc-4c21 ; Cc1cc(C)c(-c2cc3c4c(c2)N2c5ccccc5[Si](c5ccccc5)(c5ccccc5)c5cccc(c52)B4n2c4c-3cccc4c3ccc4ccccc4c32)c(C)c1] 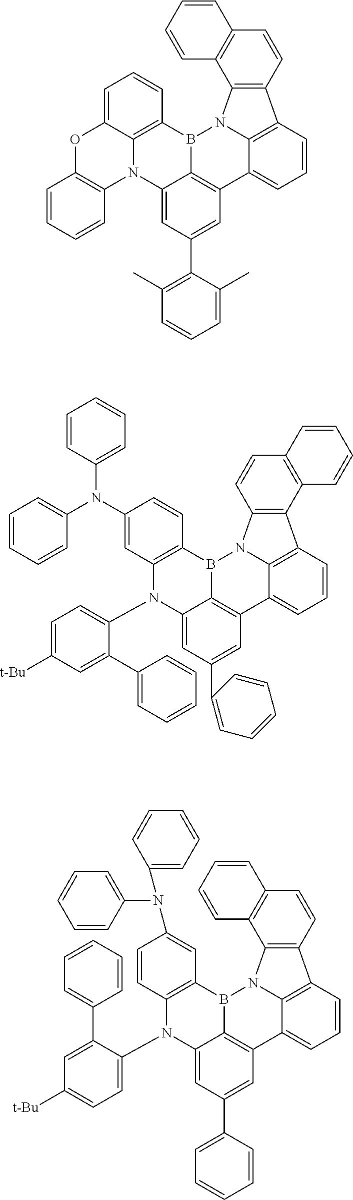 [SMILES: Cc1cccc(C)c1-c1cc2c3c(c1)N1c4ccccc4Oc4cccc(c41)B3n1c3c-2cccc3c2ccc3ccccc3c21 ; CC(C)(C)c1ccc(N2c3cc(N(c4ccccc4)c4ccccc4)ccc3B3c4c(cc(-c5ccccc5)cc42)-c2cccc4c5c6ccccc6ccc5n3c24)c(-c2ccccc2)c1 ; CC(C)(C)c1ccc(N2c3ccc(N(c4ccccc4)c4ccccc4)cc3B3c4c(cc(-c5ccccc5)cc42)-c2cccc4c5ccc6ccccc6c5n3c24)c(-c2ccccc2)c1] 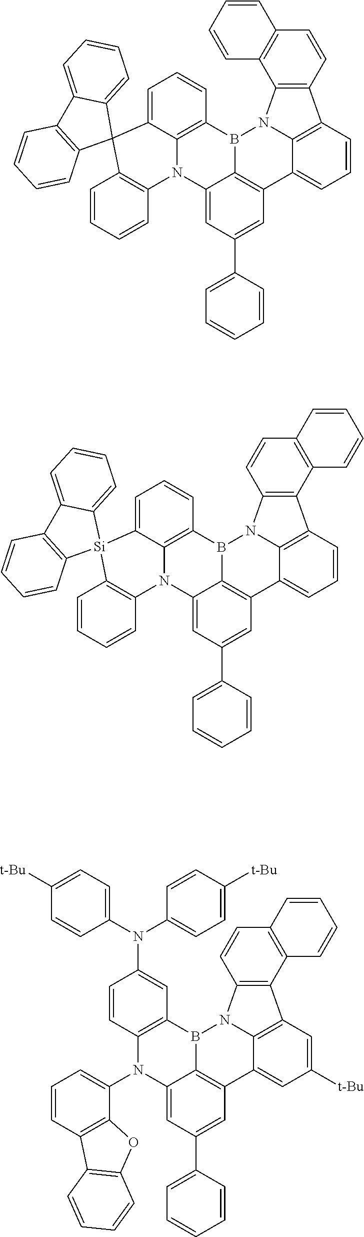 [SMILES: c1ccc(-c2cc3c4c(c2)N2c5ccccc5C5(c6ccccc6-c6ccccc65)c5cccc(c52)B4n2c4c-3cccc4c3ccc4ccccc4c32)cc1 ; c1ccc(-c2cc3c4c(c2)N2c5ccccc5[Si]5(c6ccccc6-c6ccccc65)c5cccc(c52)B4n2c4ccc5ccccc5c4c4cccc-3c42)cc1 ; CC(C)(C)c1ccc(N(c2ccc(C(C)(C)C)cc2)c2ccc3c(c2)B2c4c(cc(-c5ccccc5)cc4N3c3cccc4c3oc3ccccc34)-c3cc(C(C)(C)C)cc4c5c6ccccc6ccc5n2c34)cc1] 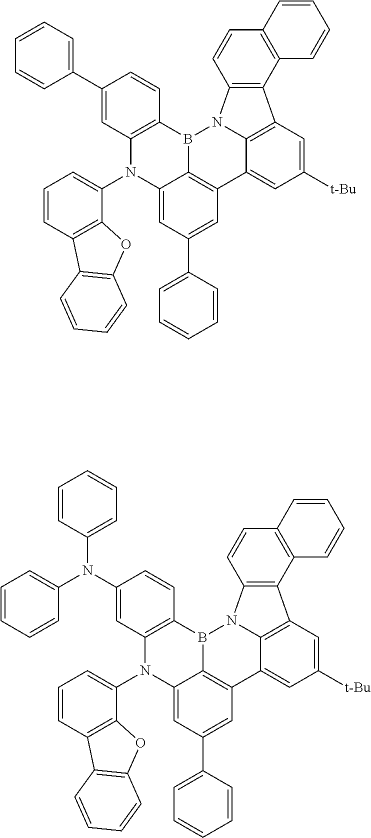 [SMILES: CC(C)(C)c1cc2c3c(c1)c1c4ccccc4ccc1n3B1c3ccc(-c4ccccc4)cc3N(c3cccc4c3oc3ccccc34)c3cc(-c4ccccc4)cc-2c31 ; CC(C)(C)c1cc2c3c(c1)c1c4ccccc4ccc1n3B1c3ccc(N(c4ccccc4)c4ccccc4)cc3N(c3cccc4c3oc3ccccc34)c3cc(-c4ccccc4)cc-2c31] 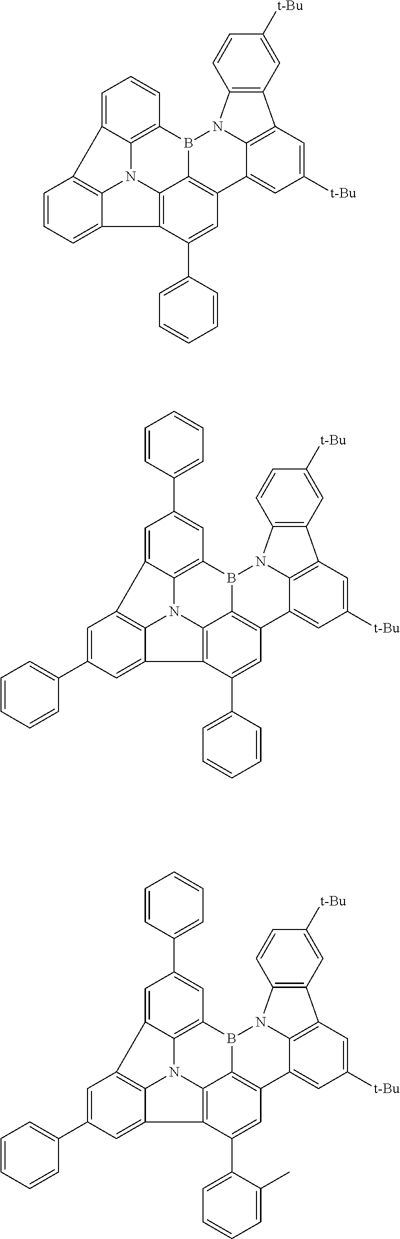 [SMILES: CC(C)(C)c1ccc2c(c1)c1cc(C(C)(C)C)cc3c1n2B1c2cccc4c5cccc6c7c(-c8ccccc8)cc-3c1c7n(c24)c56 ; CC(C)(C)c1ccc2c(c1)c1cc(C(C)(C)C)cc3c1n2B1c2cc(-c4ccccc4)cc4c5cc(-c6ccccc6)cc6c7c(-c8ccccc8)cc-3c1c7n(c24)c56 ; Cc1ccccc1-c1cc2c3c4c1c1cc(-c5ccccc5)cc5c6cc(-c7ccccc7)cc(c6n4c51)B3n1c3ccc(C(C)(C)C)cc3c3cc(C(C)(C)C)cc-2c31] 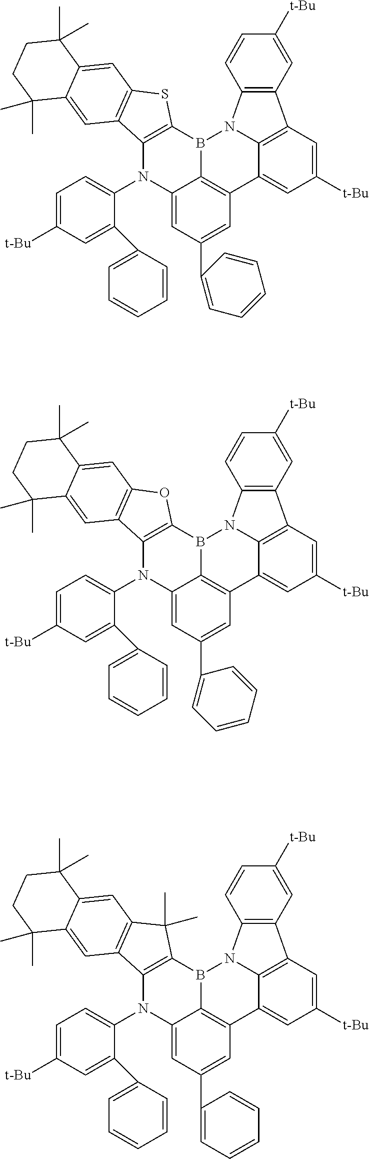 [SMILES: CC(C)(C)c1ccc(N2c3cc(-c4ccccc4)cc4c3B(c3sc5cc6c(cc5c32)C(C)(C)CCC6(C)C)n2c3ccc(C(C)(C)C)cc3c3cc(C(C)(C)C)cc-4c32)c(-c2ccccc2)c1 ; CC(C)(C)c1ccc(N2c3cc(-c4ccccc4)cc4c3B(c3oc5cc6c(cc5c32)C(C)(C)CCC6(C)C)n2c3ccc(C(C)(C)C)cc3c3cc(C(C)(C)C)cc-4c32)c(-c2ccccc2)c1 ; CC(C)(C)c1ccc(N2C3=C(B4c5c(cc(-c6ccccc6)cc52)-c2cc(C(C)(C)C)cc5c6cc(C(C)(C)C)ccc6n4c25)C(C)(C)c2cc4c(cc23)C(C)(C)CCC4(C)C)c(-c2ccccc2)c1] 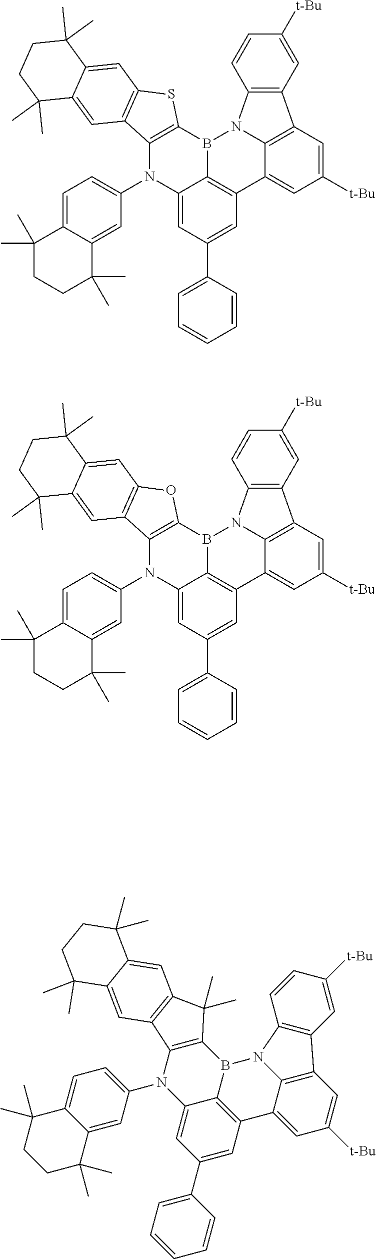 [SMILES: CC(C)(C)c1ccc2c(c1)c1cc(C(C)(C)C)cc3c1n2B1c2sc4cc5c(cc4c2N(c2ccc4c(c2)C(C)(C)CCC4(C)C)c2cc(-c4ccccc4)cc-3c21)C(C)(C)CCC5(C)C ; CC(C)(C)c1ccc2c(c1)c1cc(C(C)(C)C)cc3c1n2B1c2oc4cc5c(cc4c2N(c2ccc4c(c2)C(C)(C)CCC4(C)C)c2cc(-c4ccccc4)cc-3c21)C(C)(C)CCC5(C)C ; CC(C)(C)c1ccc2c(c1)c1cc(C(C)(C)C)cc3c1n2B1C2=C(c4cc5c(cc4C2(C)C)C(C)(C)CCC5(C)C)N(c2ccc4c(c2)C(C)(C)CCC4(C)C)c2cc(-c4ccccc4)cc-3c21] 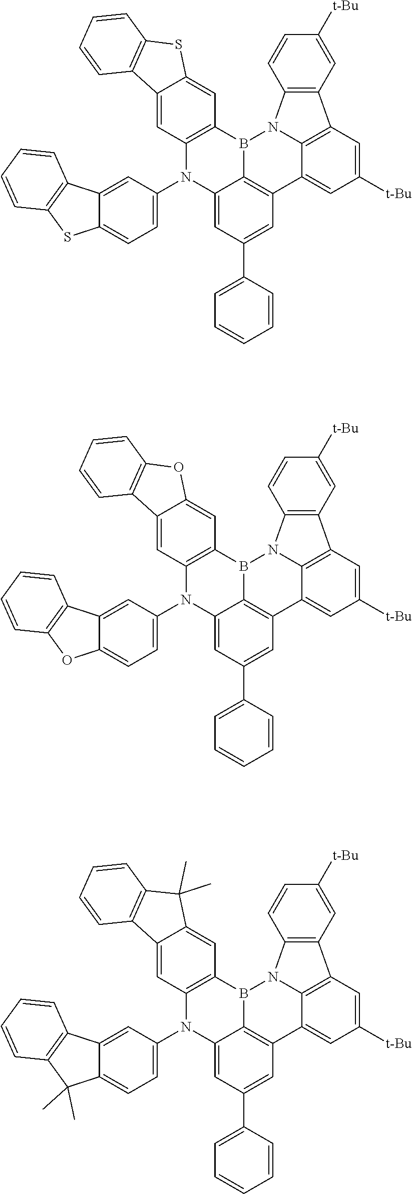 [SMILES: CC(C)(C)c1ccc2c(c1)c1cc(C(C)(C)C)cc3c1n2B1c2cc4sc5ccccc5c4cc2N(c2ccc4sc5ccccc5c4c2)c2cc(-c4ccccc4)cc-3c21 ; CC(C)(C)c1ccc2c(c1)c1cc(C(C)(C)C)cc3c1n2B1c2cc4oc5ccccc5c4cc2N(c2ccc4oc5ccccc5c4c2)c2cc(-c4ccccc4)cc-3c21 ; CC(C)(C)c1ccc2c(c1)c1cc(C(C)(C)C)cc3c1n2B1c2cc4c(cc2N(c2ccc5c(c2)-c2ccccc2C5(C)C)c2cc(-c5ccccc5)cc-3c21)-c1ccccc1C4(C)C] 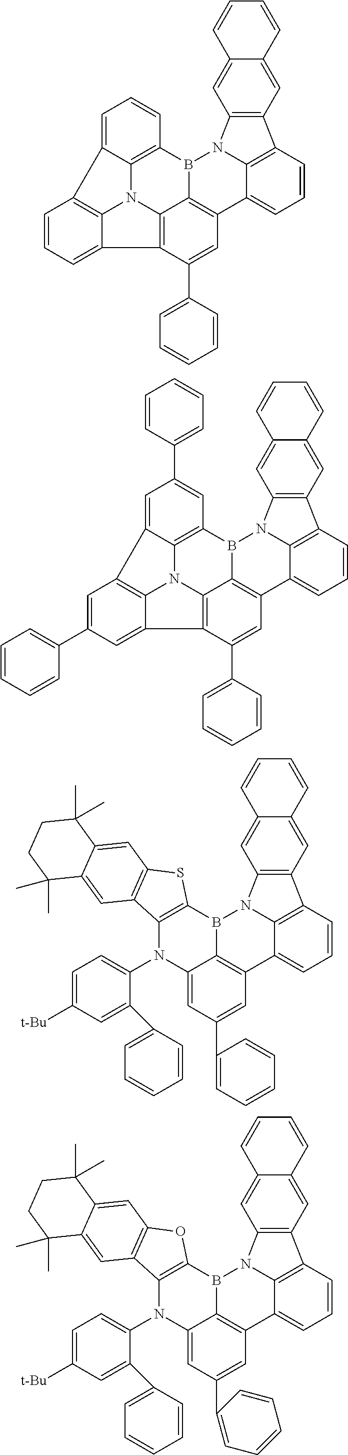 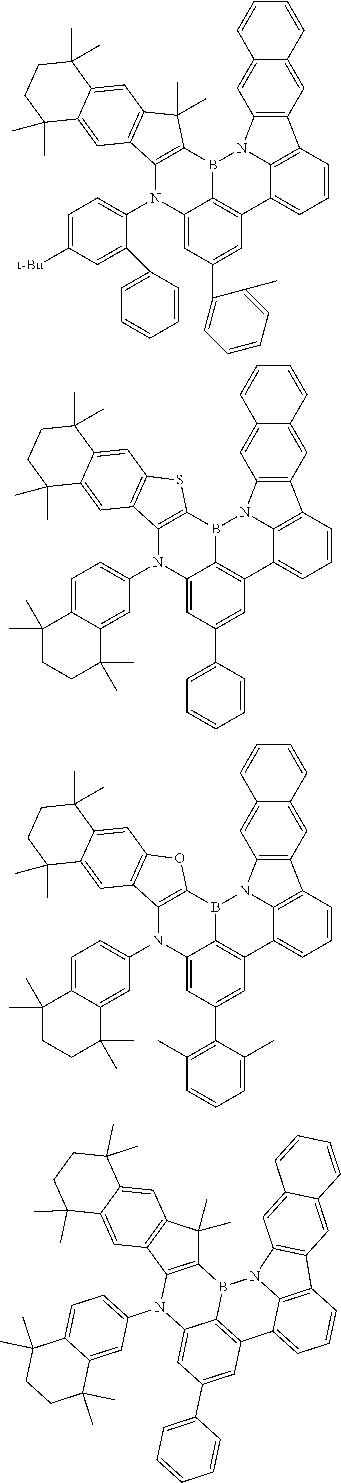 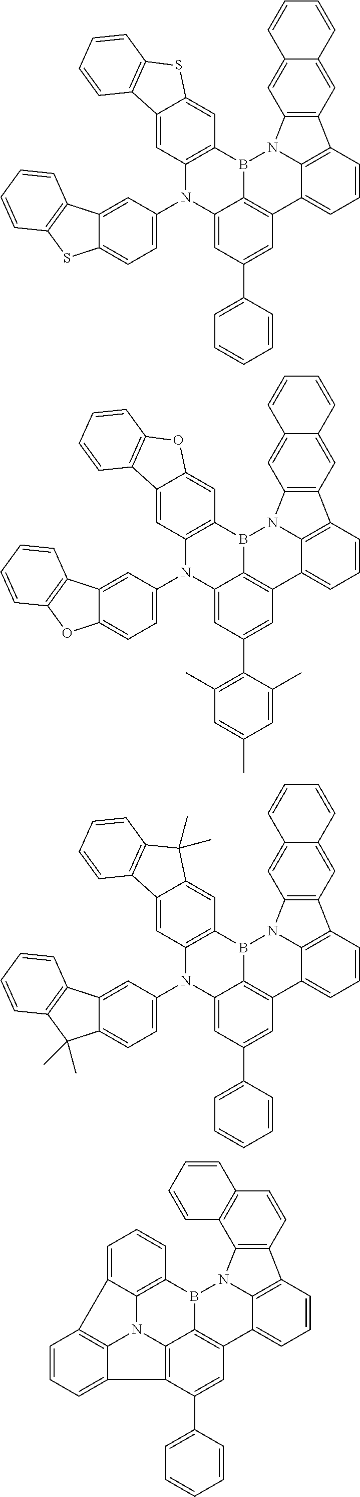 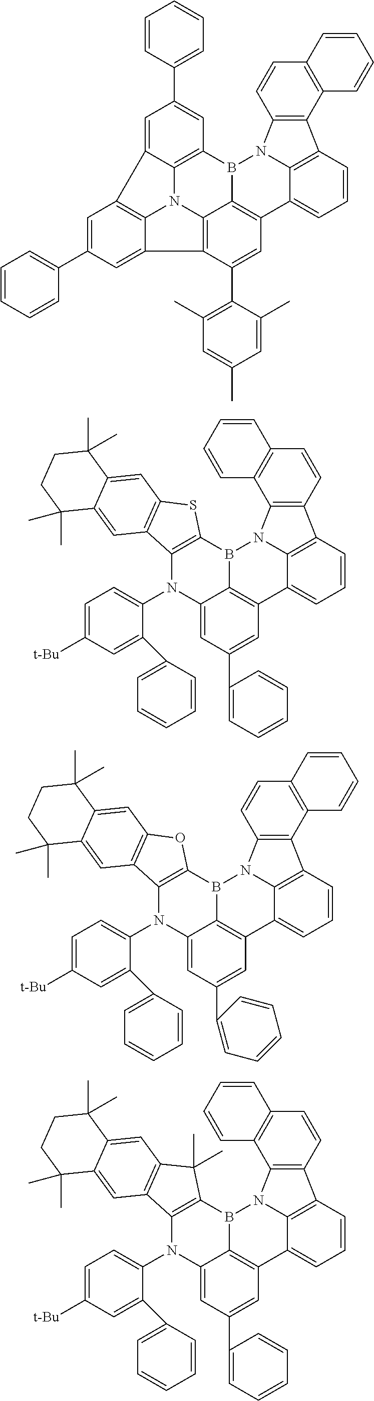 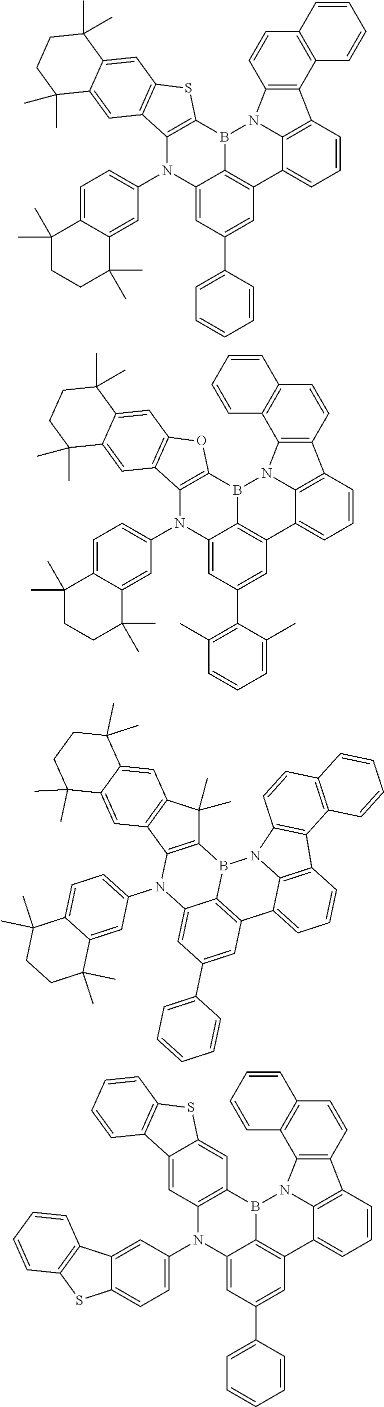 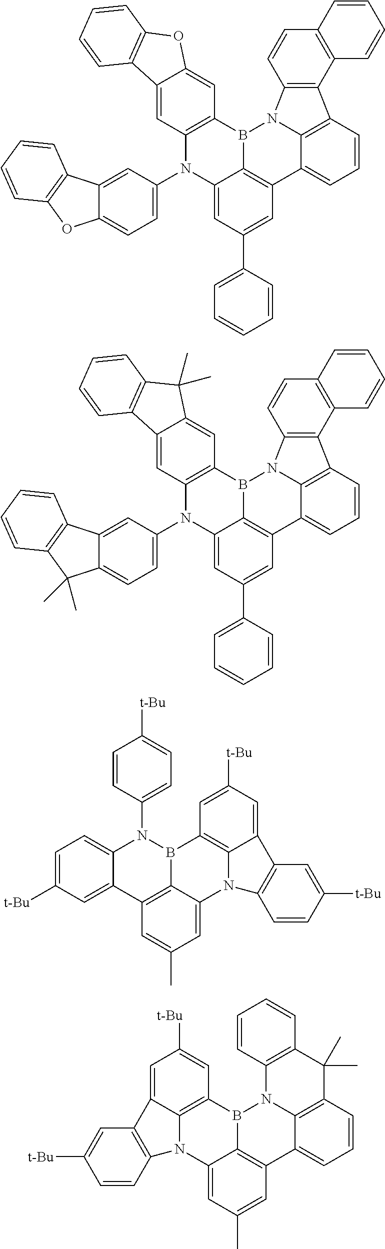 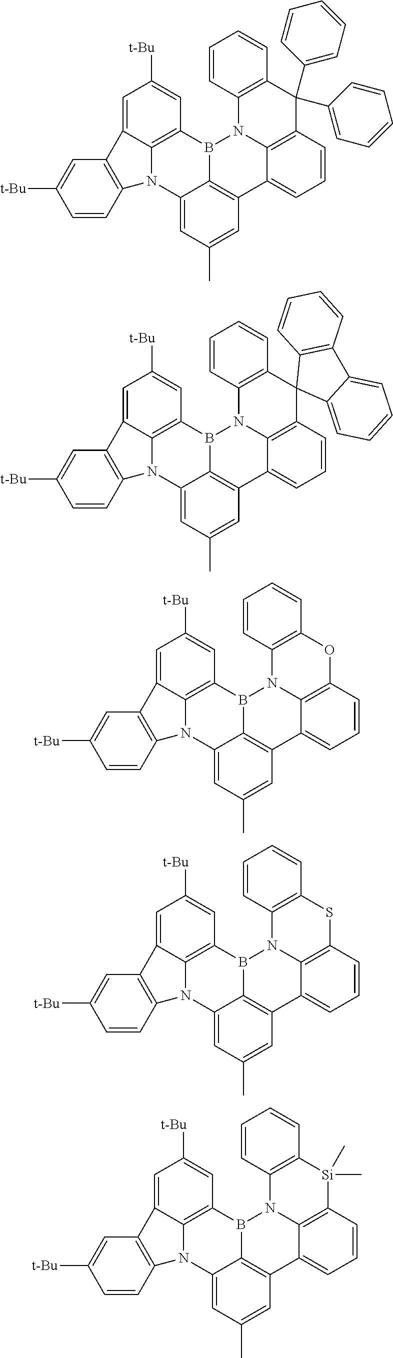 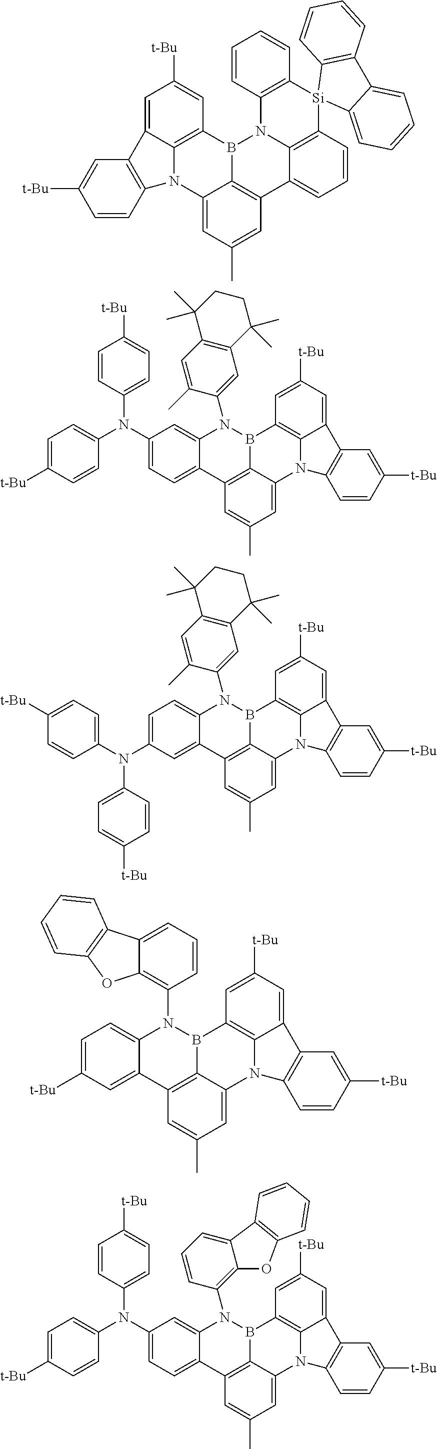 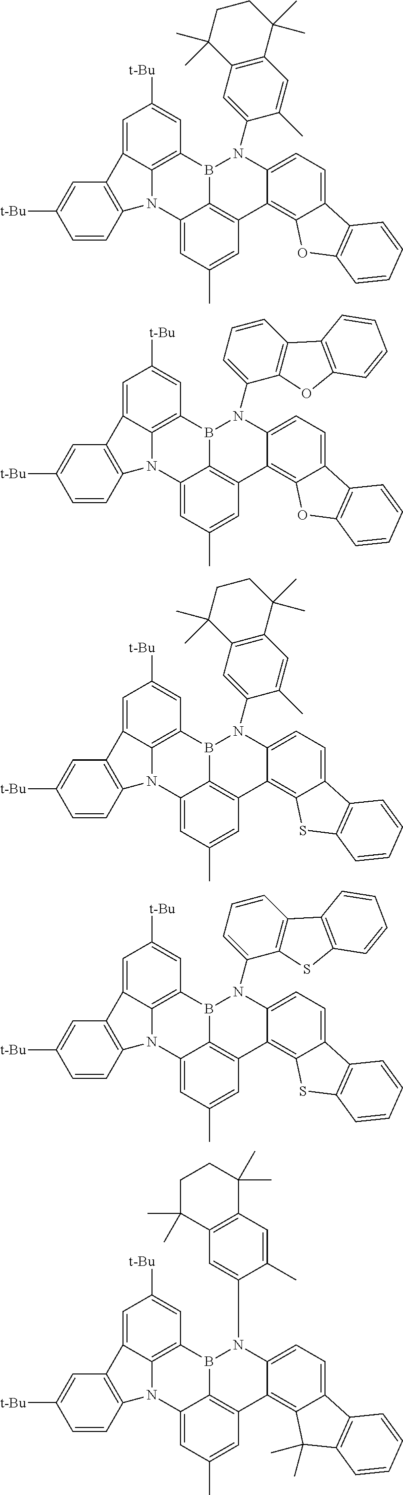 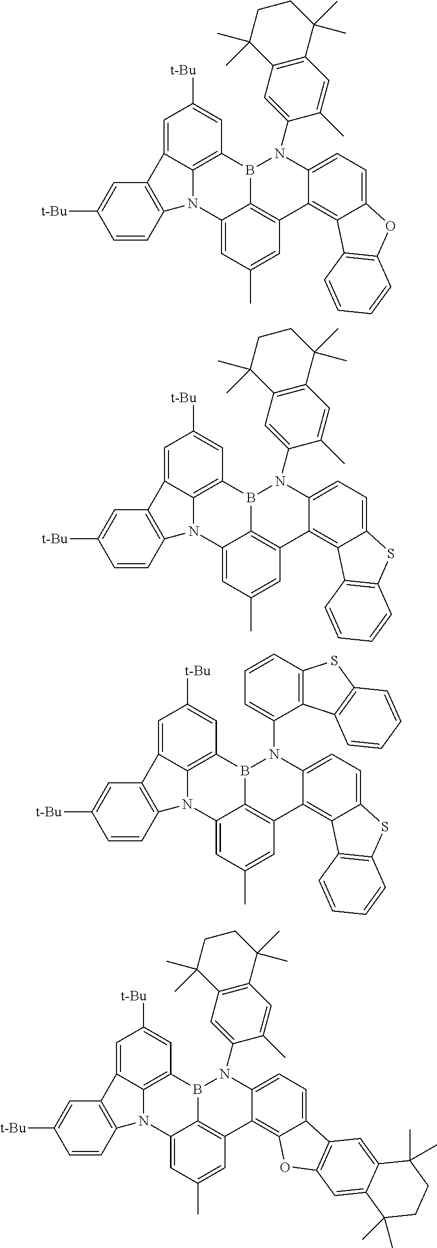 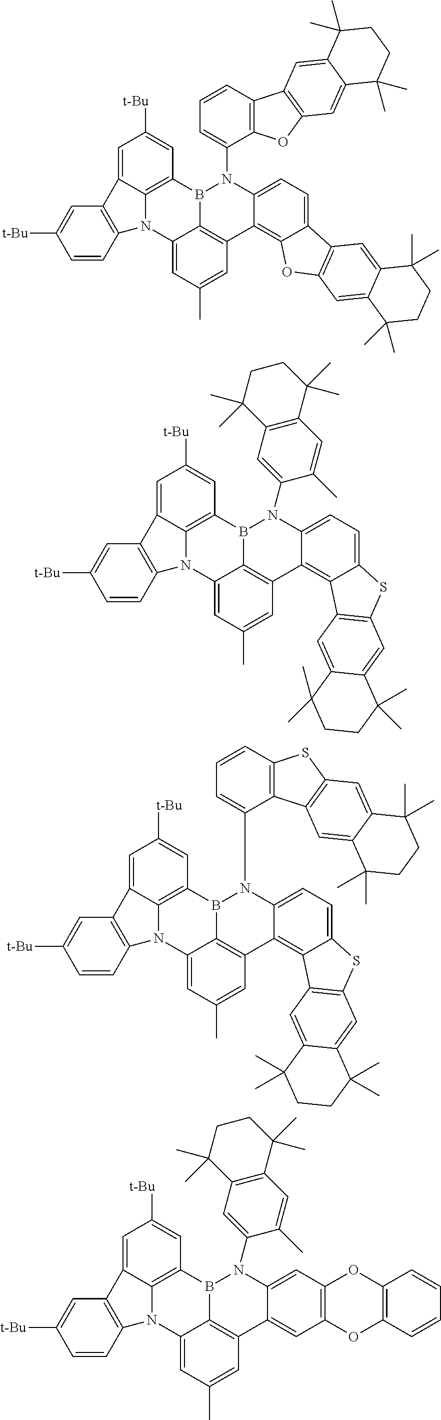 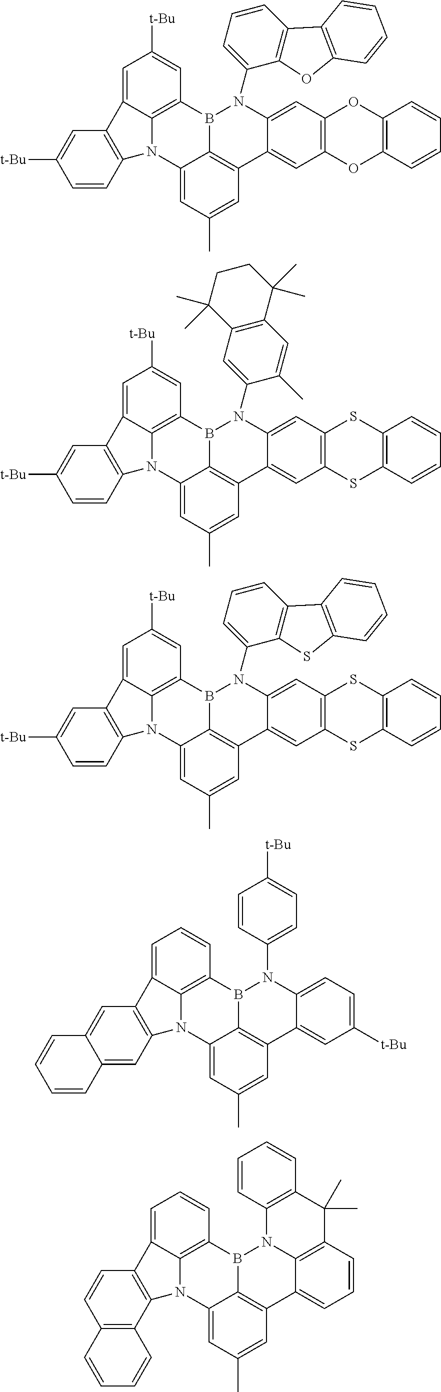 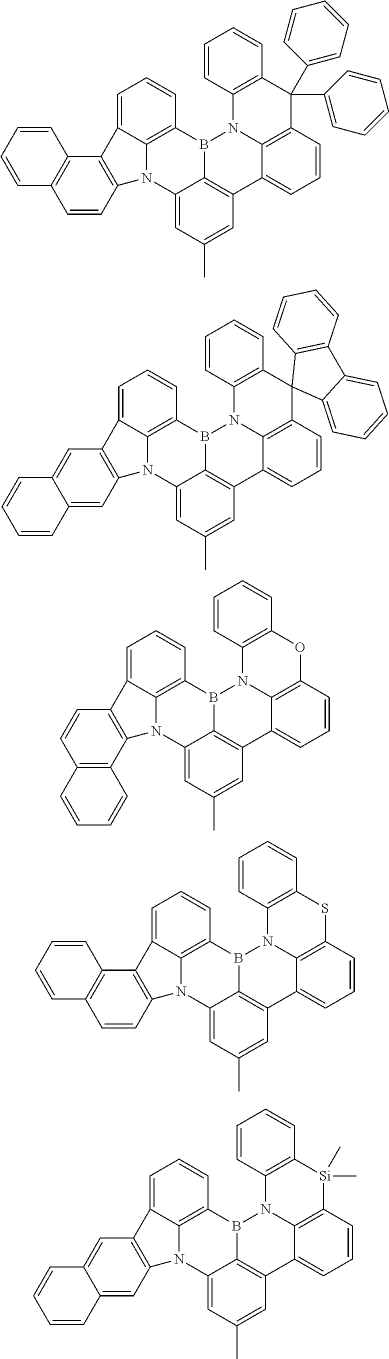 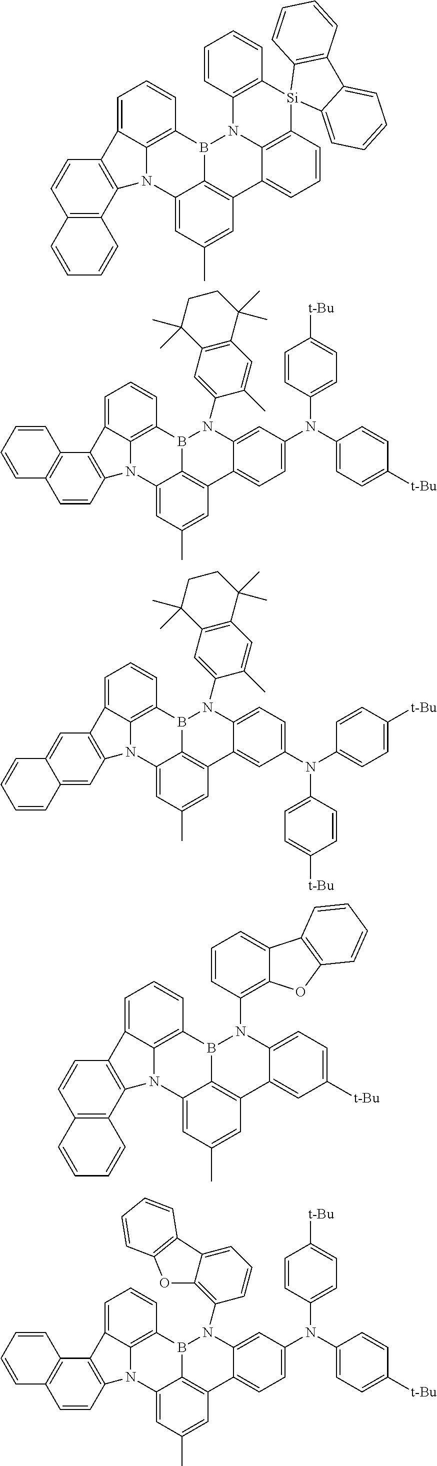 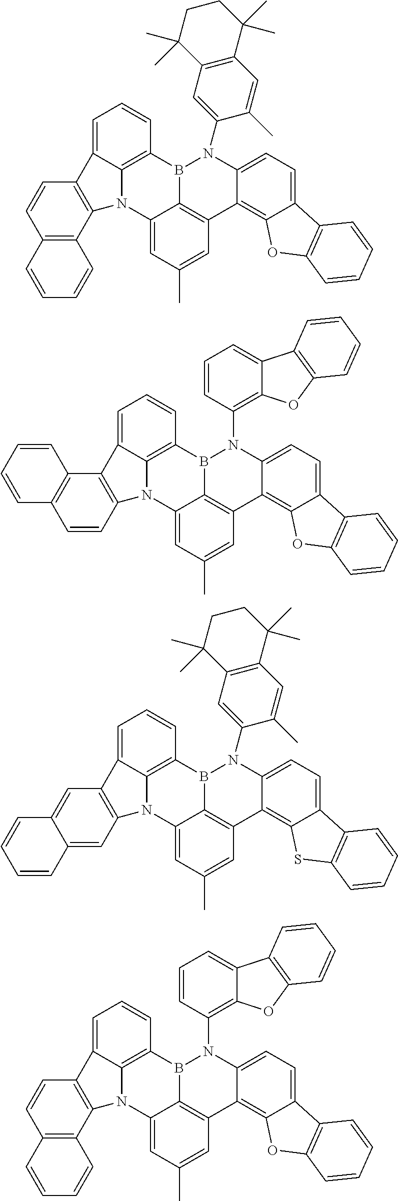 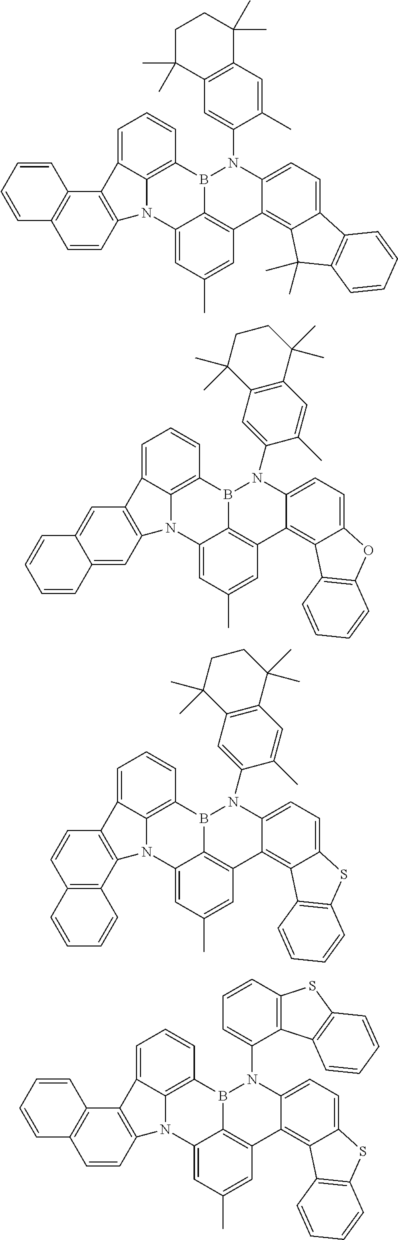 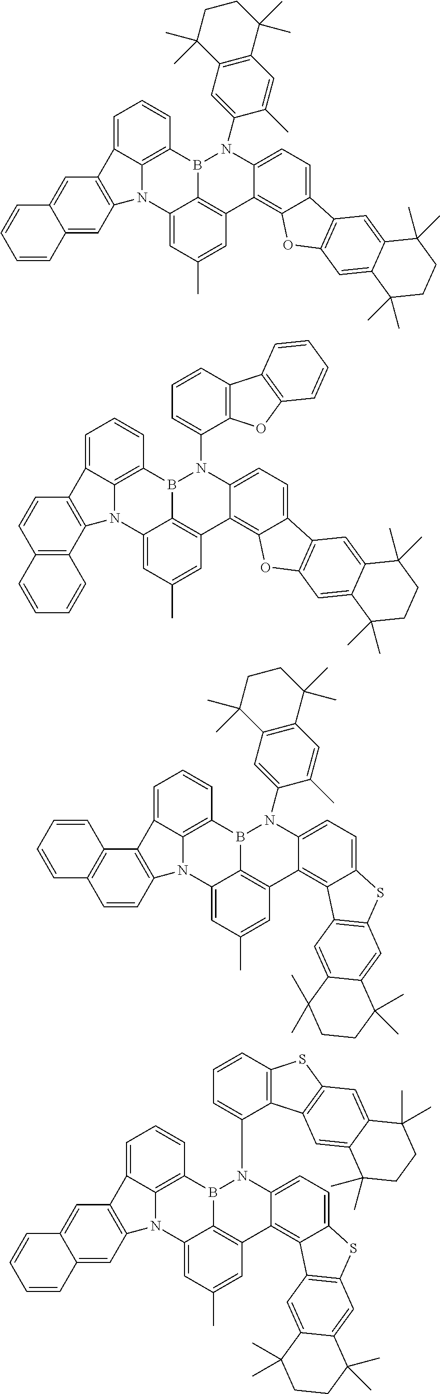 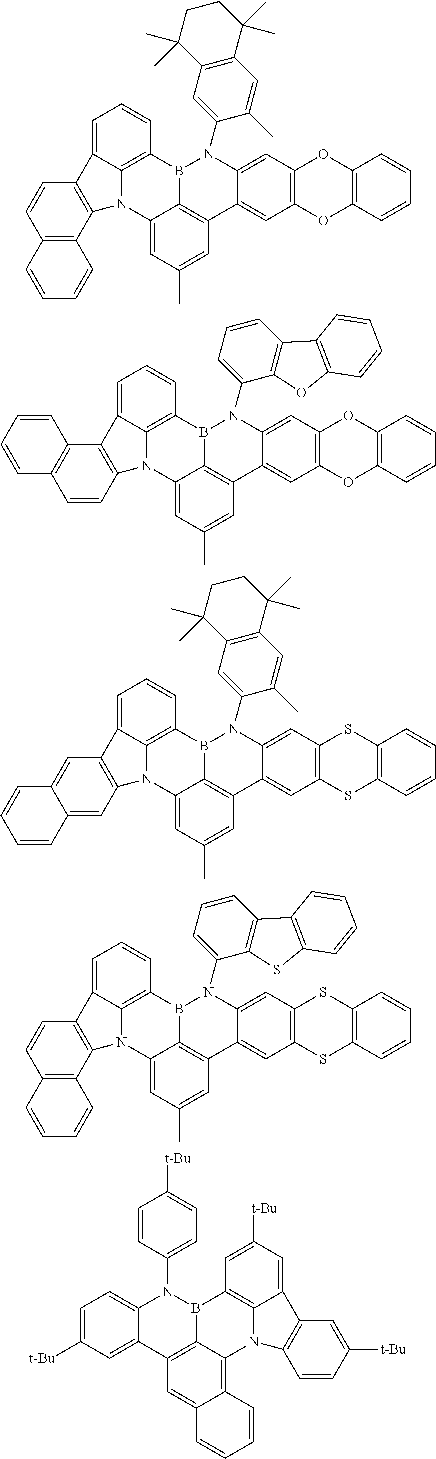 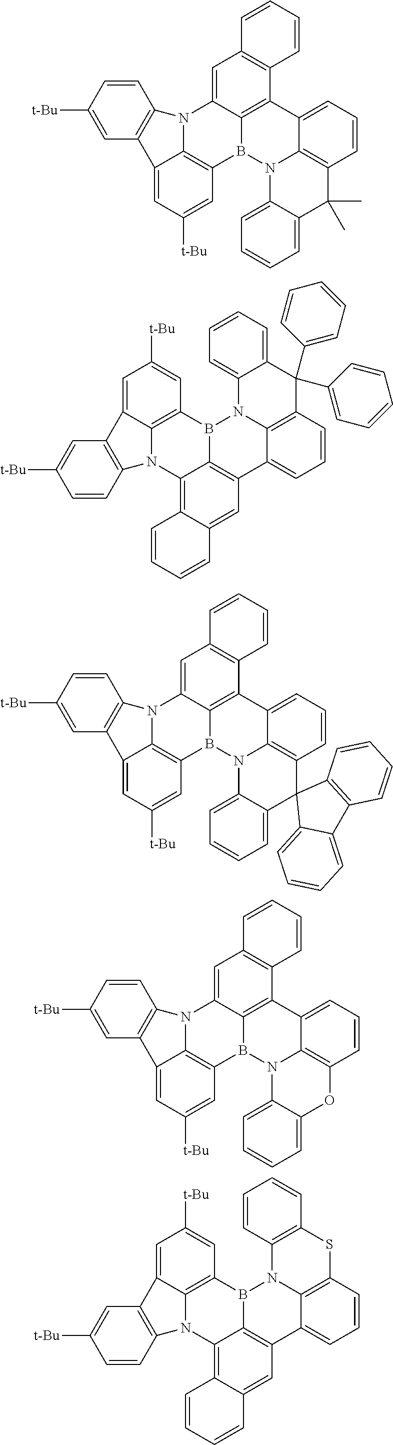 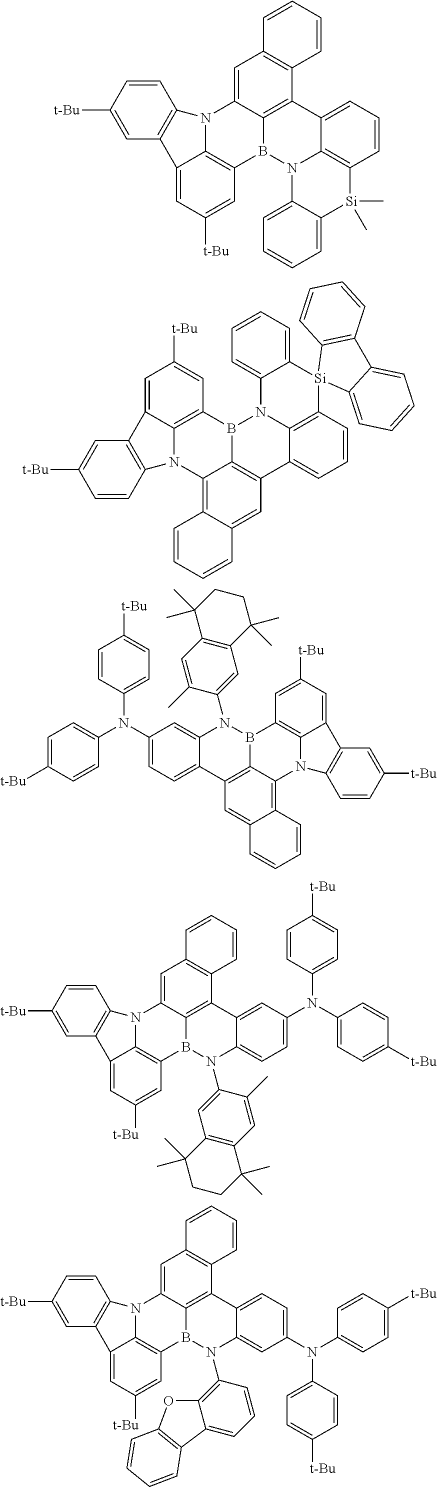 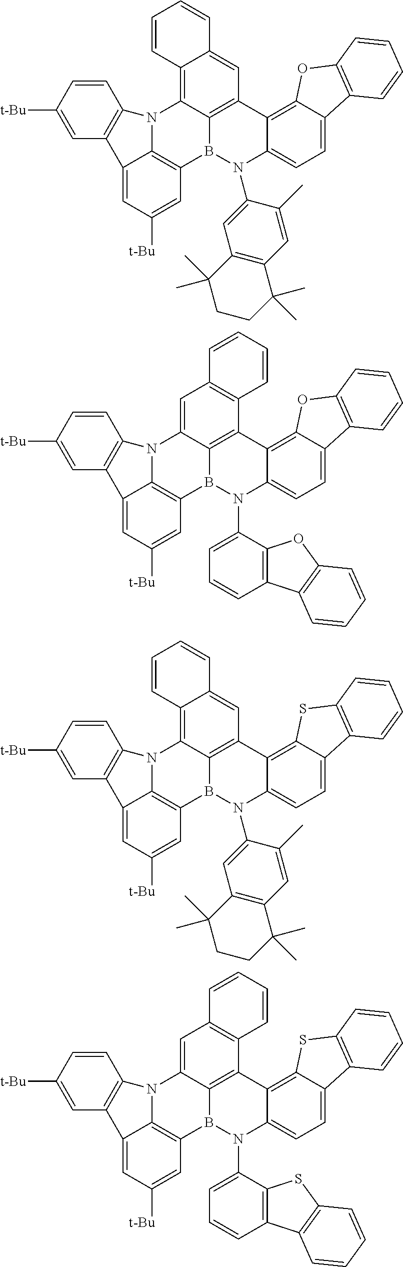 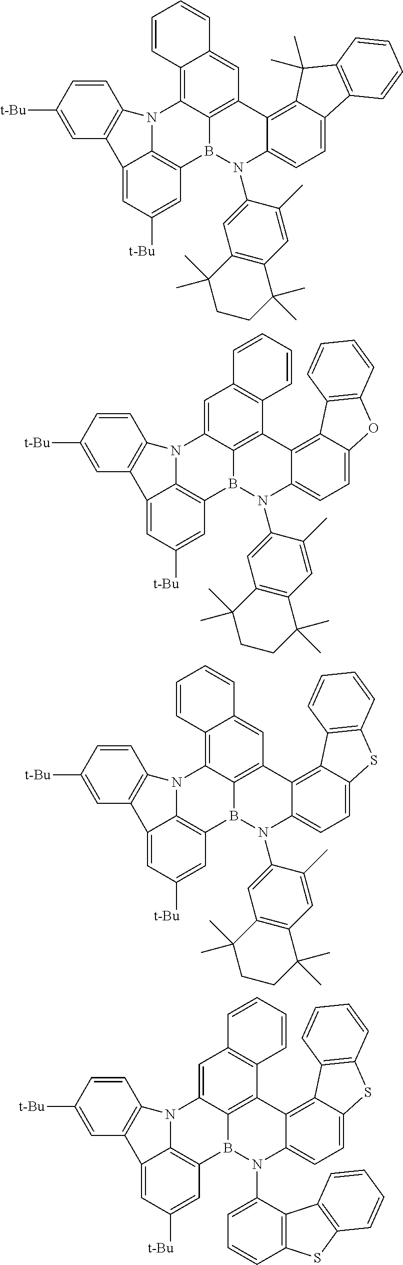 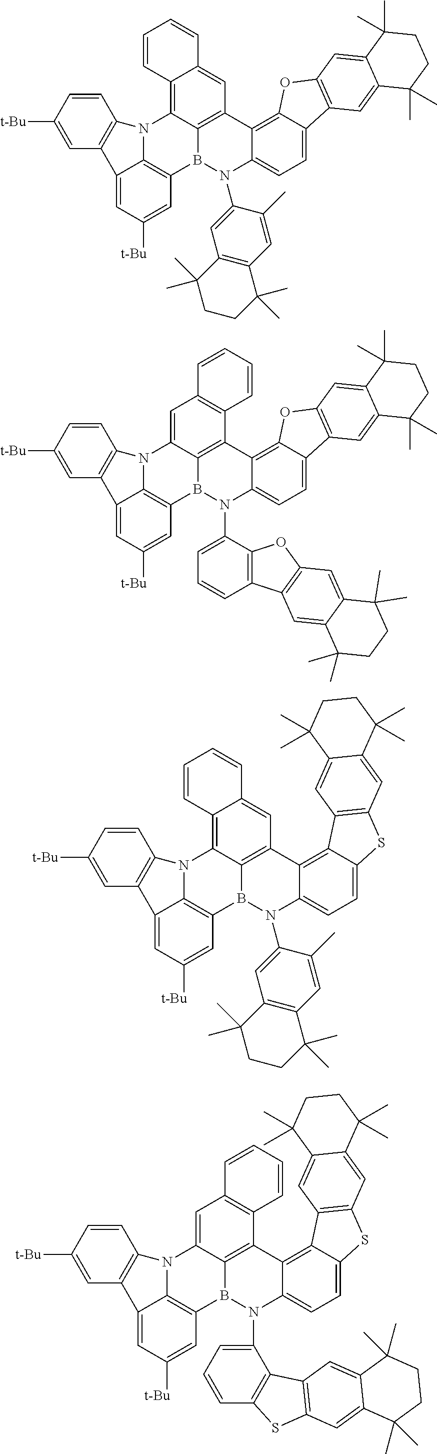 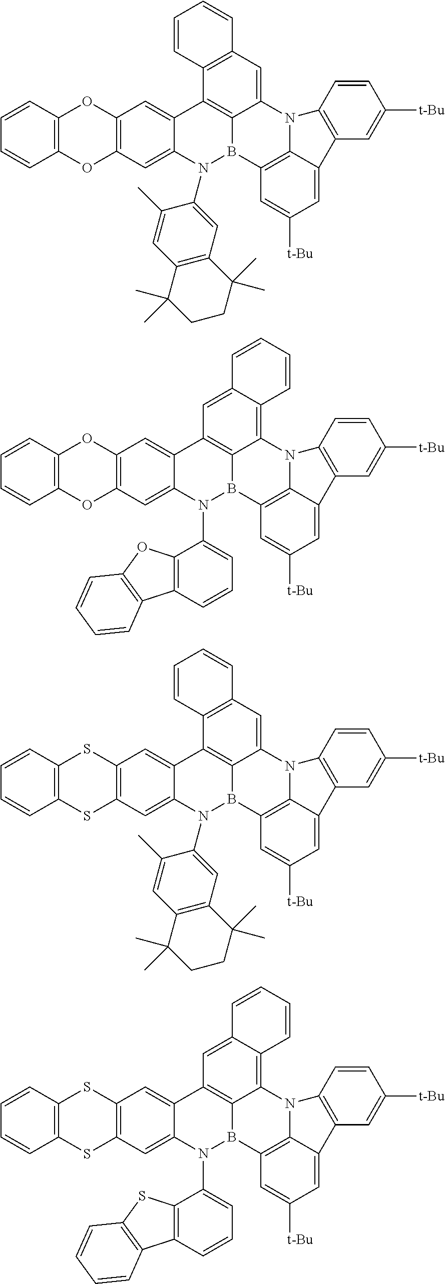 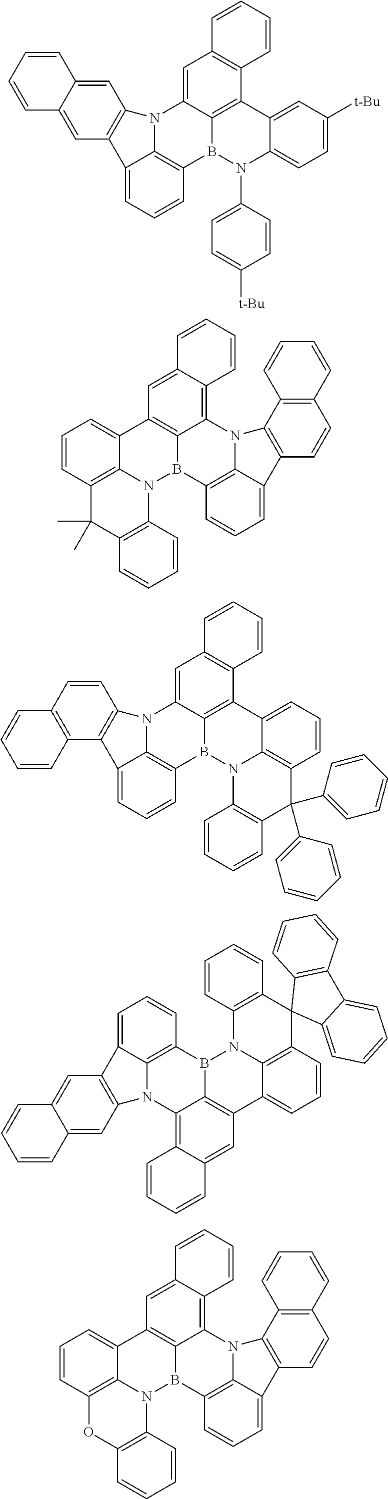 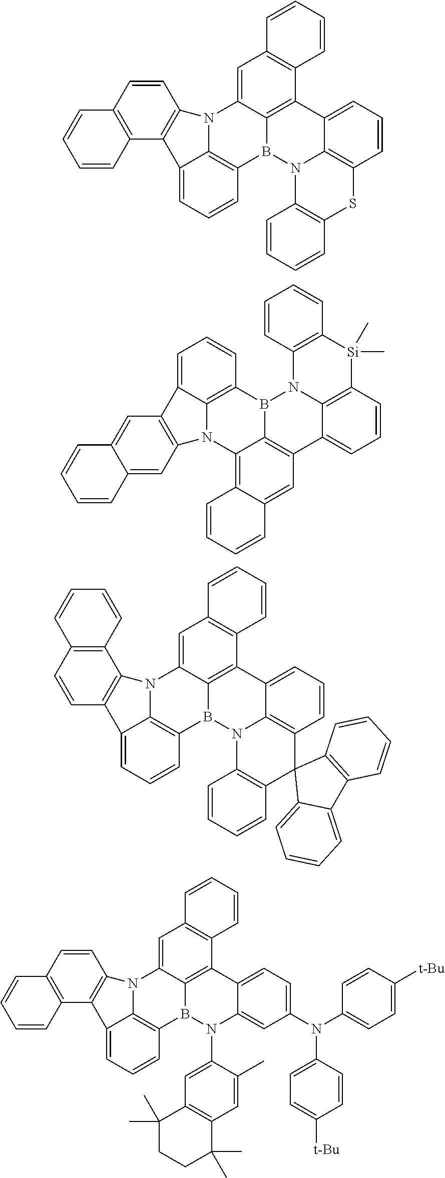 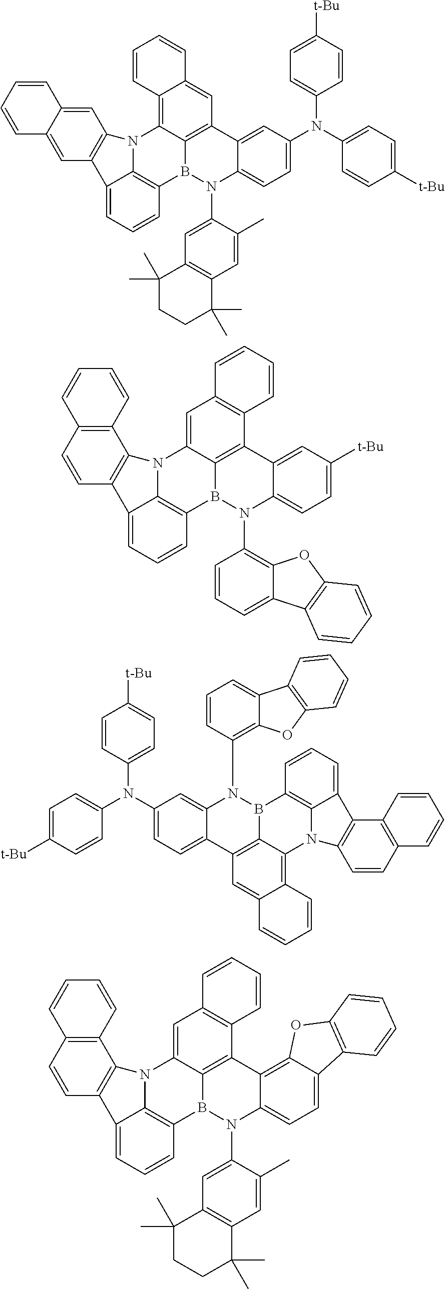 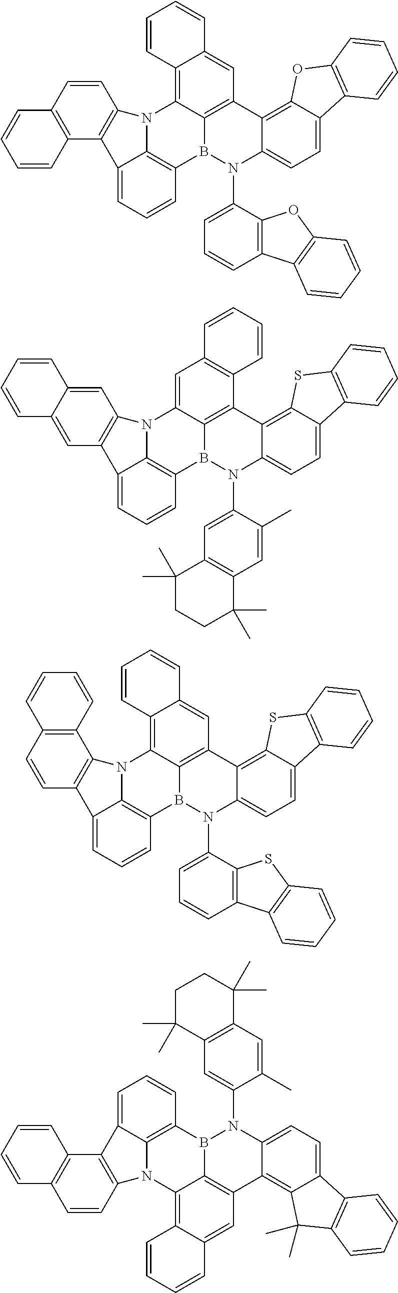 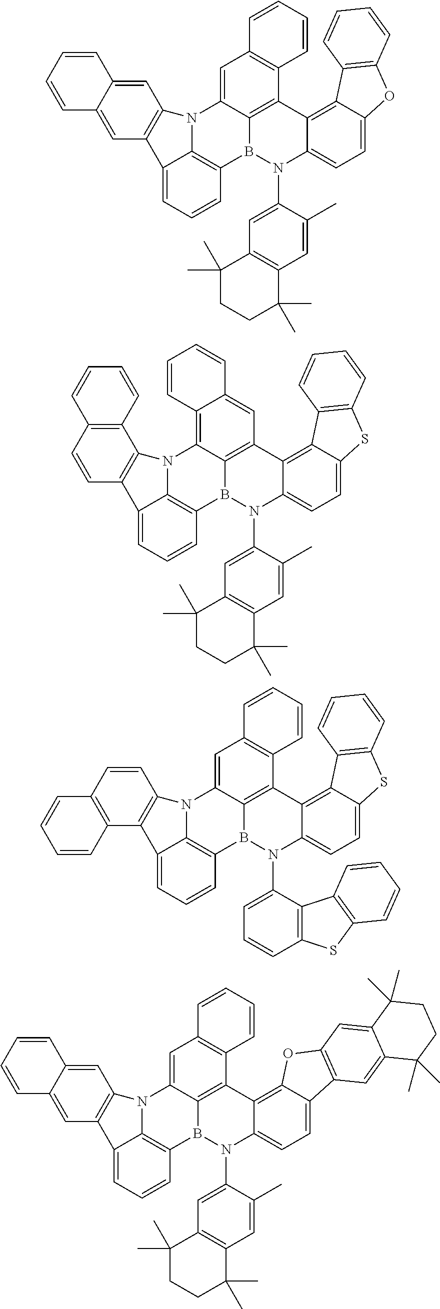 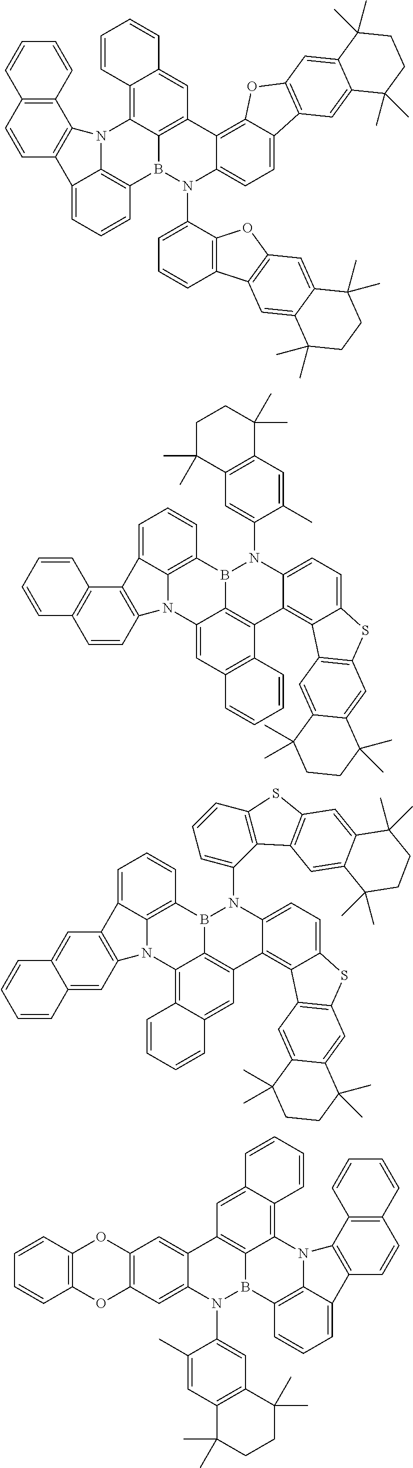 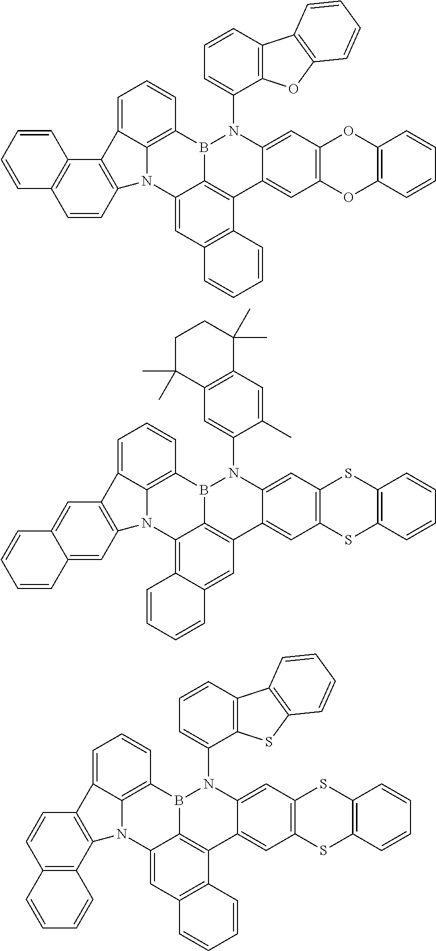 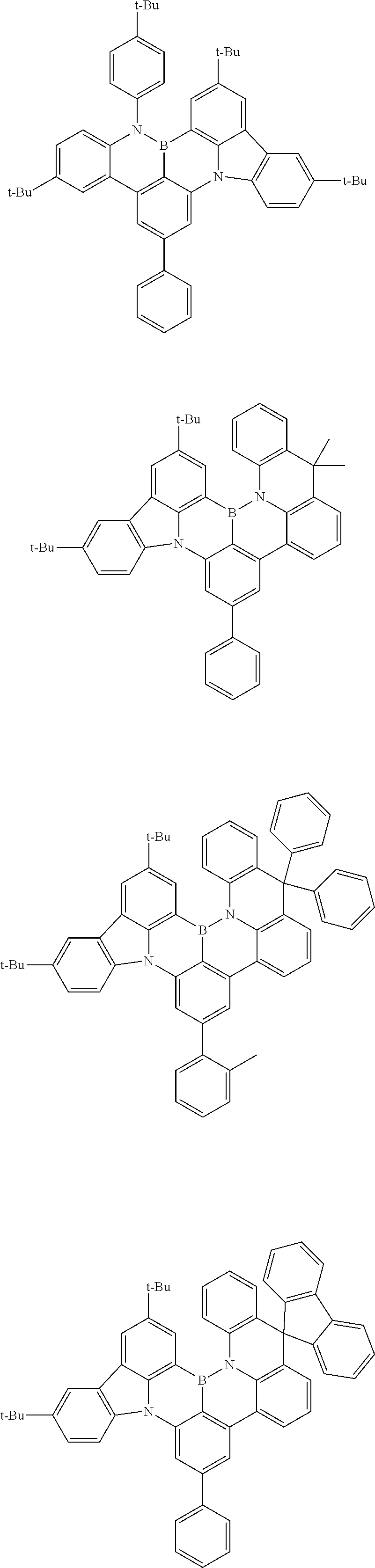 [SMILES: CC(C)(C)c1ccc(N2B3c4c(cc(-c5ccccc5)cc4-n4c5ccc(C(C)(C)C)cc5c5cc(C(C)(C)C)cc3c54)-c3cc(C(C)(C)C)ccc32)cc1 ; CC(C)(C)c1ccc2c(c1)c1cc(C(C)(C)C)cc3c1n2-c1cc(-c2ccccc2)cc2c1B3N1c3ccccc3C(C)(C)c3cccc-2c31 ; Cc1ccccc1-c1cc2c3c(c1)-n1c4ccc(C(C)(C)C)cc4c4cc(C(C)(C)C)cc(c41)B3N1c3ccccc3C(c3ccccc3)(c3ccccc3)c3cccc-2c31 ; CC(C)(C)c1ccc2c(c1)c1cc(C(C)(C)C)cc3c1n2-c1cc(-c2ccccc2)cc2c1B3N1c3ccccc3C3(c4ccccc4-c4ccccc43)c3cccc-2c31] 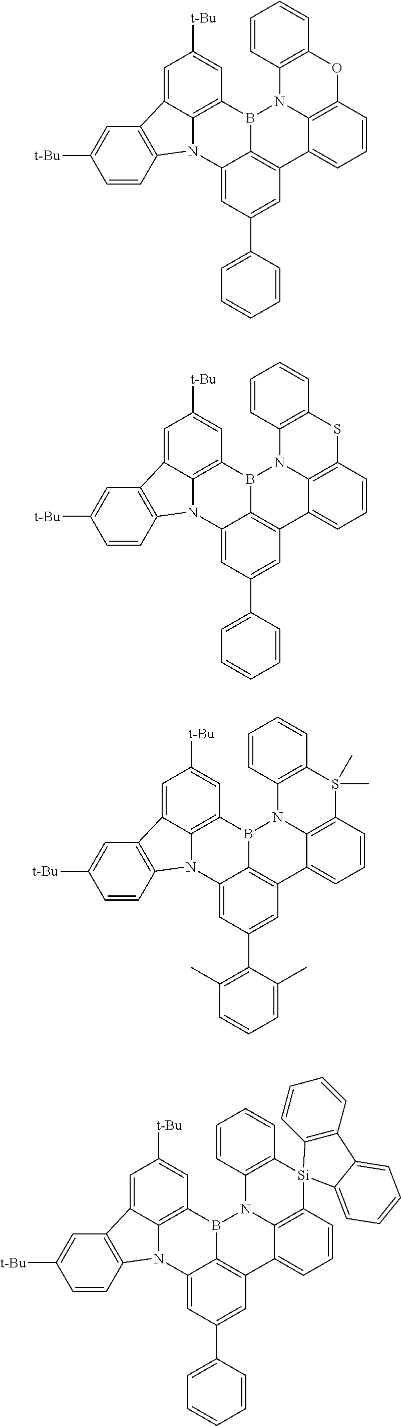 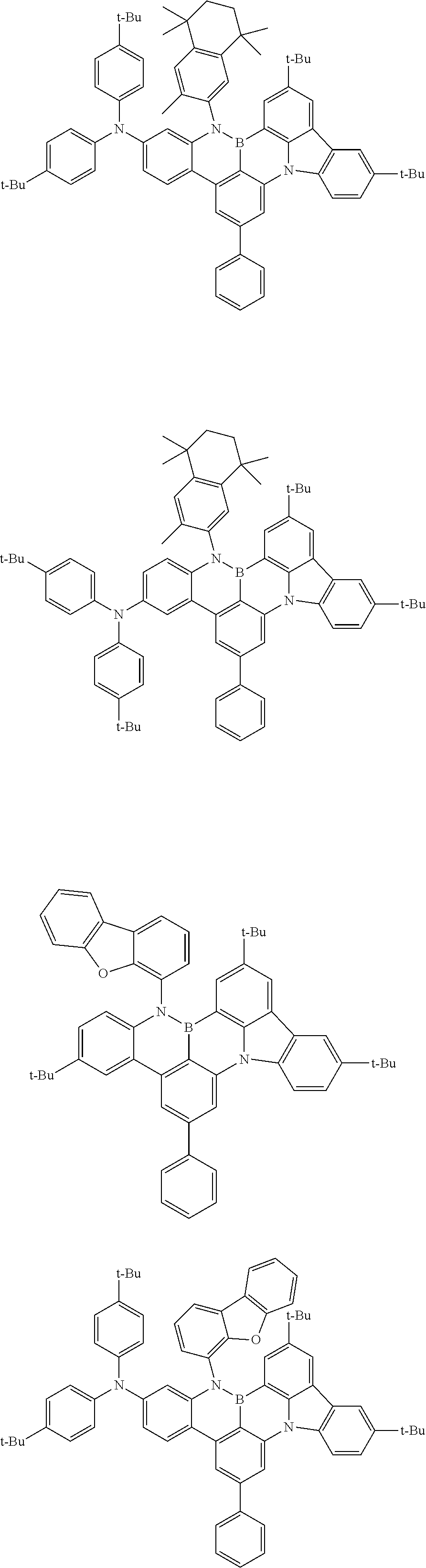 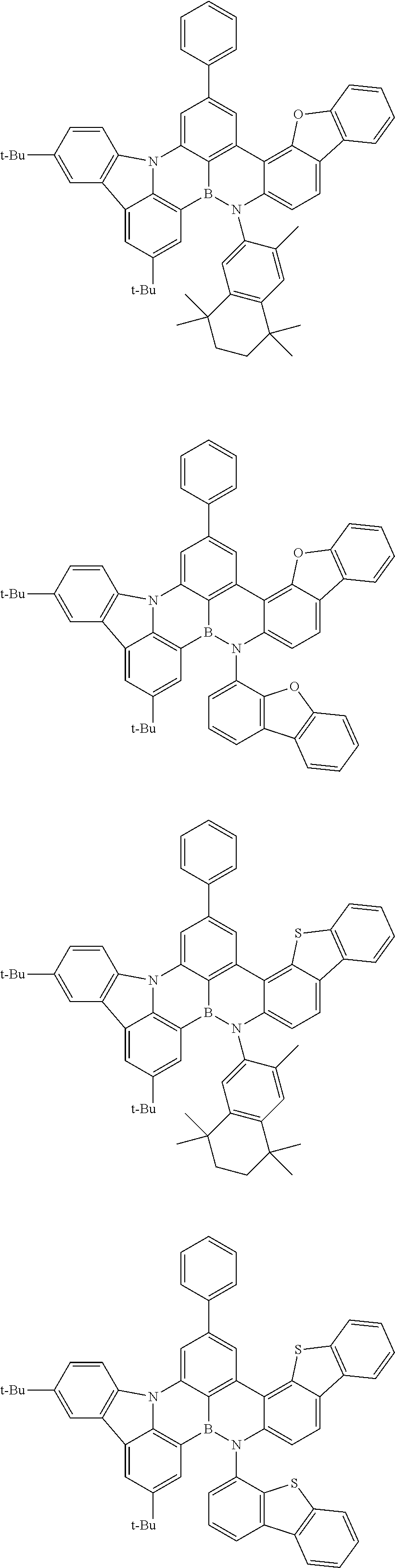 [SMILES: Cc1cc2c(cc1N1B3c4c(cc(-c5ccccc5)cc4-n4c5ccc(C(C)(C)C)cc5c5cc(C(C)(C)C)cc3c54)-c3c1ccc1c3oc3ccccc31)C(C)(C)CCC2(C)C ; CC(C)(C)c1ccc2c(c1)c1cc(C(C)(C)C)cc3c1n2-c1cc(-c2ccccc2)cc2c1B3N(c1cccc3c1oc1ccccc13)c1ccc3c(oc4ccccc43)c1-2 ; Cc1cc2c(cc1N1B3c4c(cc(-c5ccccc5)cc4-n4c5ccc(C(C)(C)C)cc5c5cc(C(C)(C)C)cc3c54)-c3c1ccc1c3sc3ccccc31)C(C)(C)CCC2(C)C ; CC(C)(C)c1ccc2c(c1)c1cc(C(C)(C)C)cc3c1n2-c1cc(-c2ccccc2)cc2c1B3N(c1cccc3c1sc1ccccc13)c1ccc3c(sc4ccccc43)c1-2] 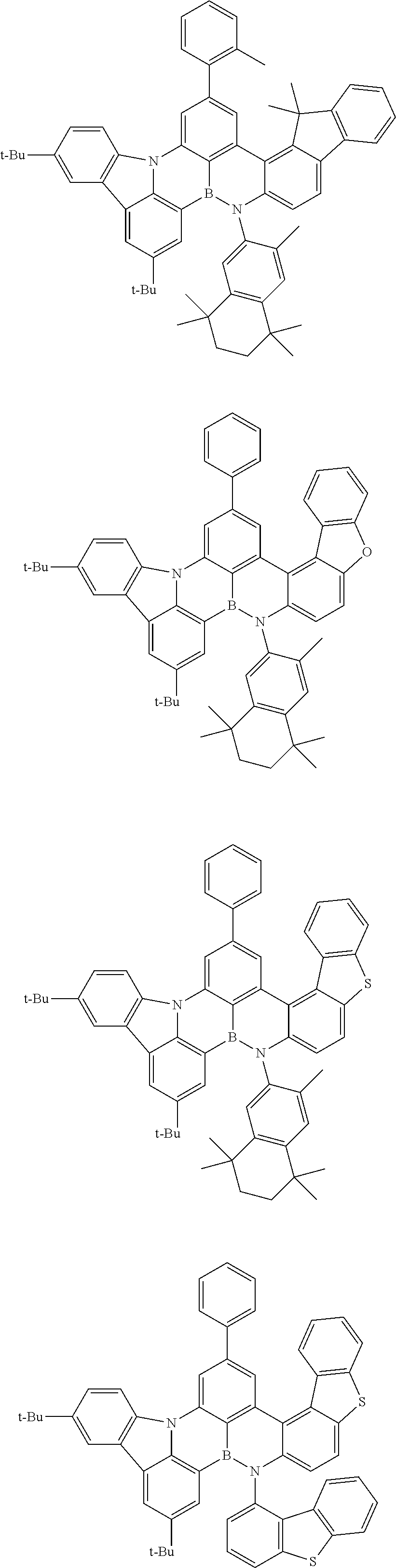 [SMILES: Cc1ccccc1-c1cc2c3c(c1)-n1c4ccc(C(C)(C)C)cc4c4cc(C(C)(C)C)cc(c41)B3N(c1cc3c(cc1C)C(C)(C)CCC3(C)C)c1ccc3c(c1-2)C(C)(C)c1ccccc1-3 ; Cc1cc2c(cc1N1B3c4c(cc(-c5ccccc5)cc4-n4c5ccc(C(C)(C)C)cc5c5cc(C(C)(C)C)cc3c54)-c3c1ccc1oc4ccccc4c31)C(C)(C)CCC2(C)C ; Cc1cc2c(cc1N1B3c4c(cc(-c5ccccc5)cc4-n4c5ccc(C(C)(C)C)cc5c5cc(C(C)(C)C)cc3c54)-c3c1ccc1sc4ccccc4c31)C(C)(C)CCC2(C)C ; CC(C)(C)c1ccc2c(c1)c1cc(C(C)(C)C)cc3c1n2-c1cc(-c2ccccc2)cc2c1B3N(c1cccc3sc4ccccc4c13)c1ccc3sc4ccccc4c3c1-2] 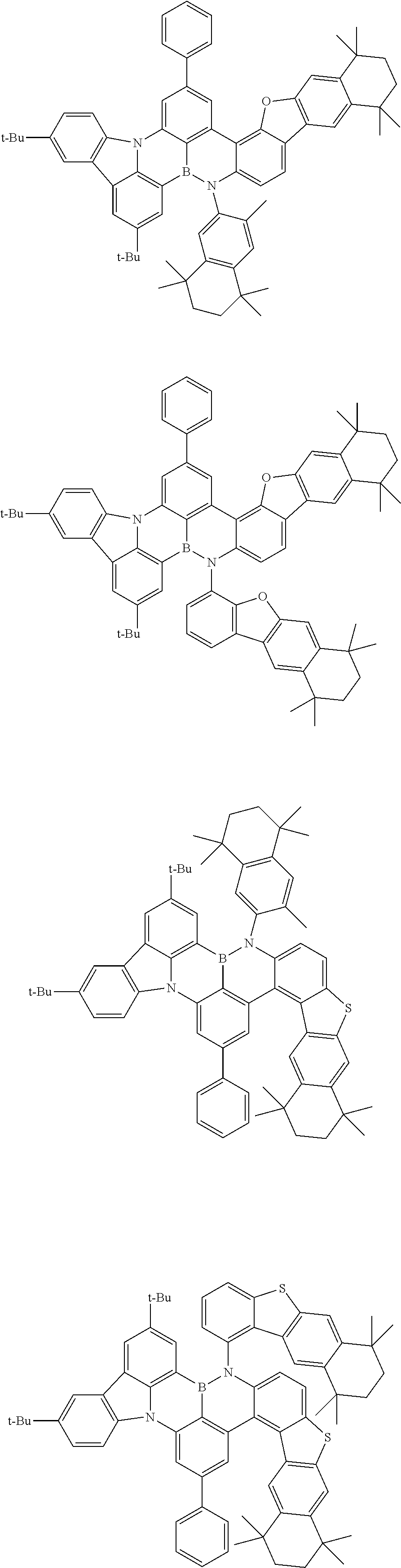 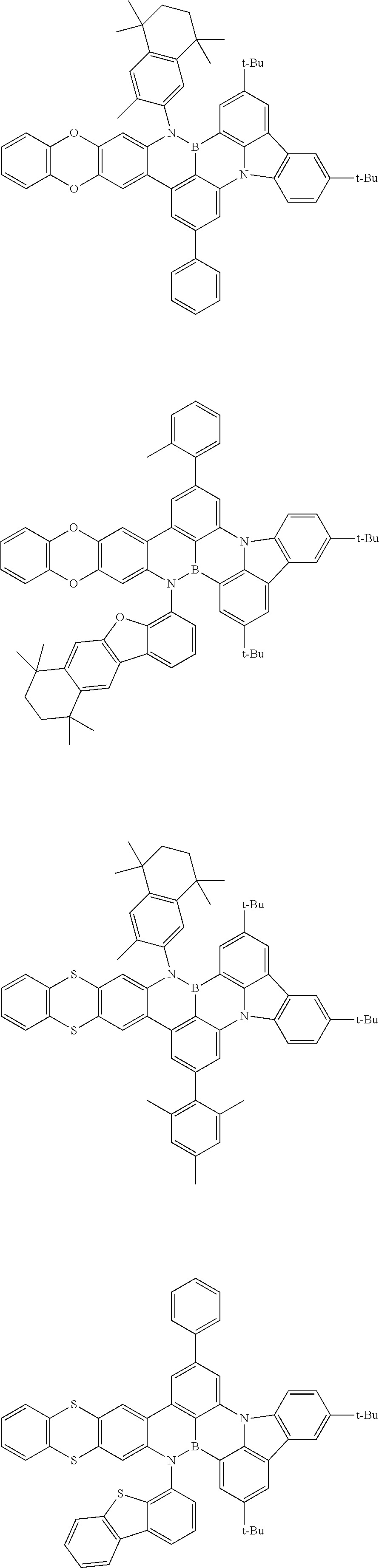 [SMILES: Cc1cc2c(cc1N1B3c4c(cc(-c5ccccc5)cc4-n4c5ccc(C(C)(C)C)cc5c5cc(C(C)(C)C)cc3c54)-c3cc4c(cc31)Oc1ccccc1O4)C(C)(C)CCC2(C)C ; Cc1ccccc1-c1cc2c3c(c1)-n1c4ccc(C(C)(C)C)cc4c4cc(C(C)(C)C)cc(c41)B3N(c1cccc3c1oc1cc4c(cc13)C(C)(C)CCC4(C)C)c1cc3c(cc1-2)Oc1ccccc1O3 ; Cc1cc(C)c(-c2cc3c4c(c2)-n2c5ccc(C(C)(C)C)cc5c5cc(C(C)(C)C)cc(c52)B4N(c2cc4c(cc2C)C(C)(C)CCC4(C)C)c2cc4c(cc2-3)Sc2ccccc2S4)c(C)c1 ; CC(C)(C)c1ccc2c(c1)c1cc(C(C)(C)C)cc3c1n2-c1cc(-c2ccccc2)cc2c1B3N(c1cccc3c1sc1ccccc13)c1cc3c(cc1-2)Sc1ccccc1S3] 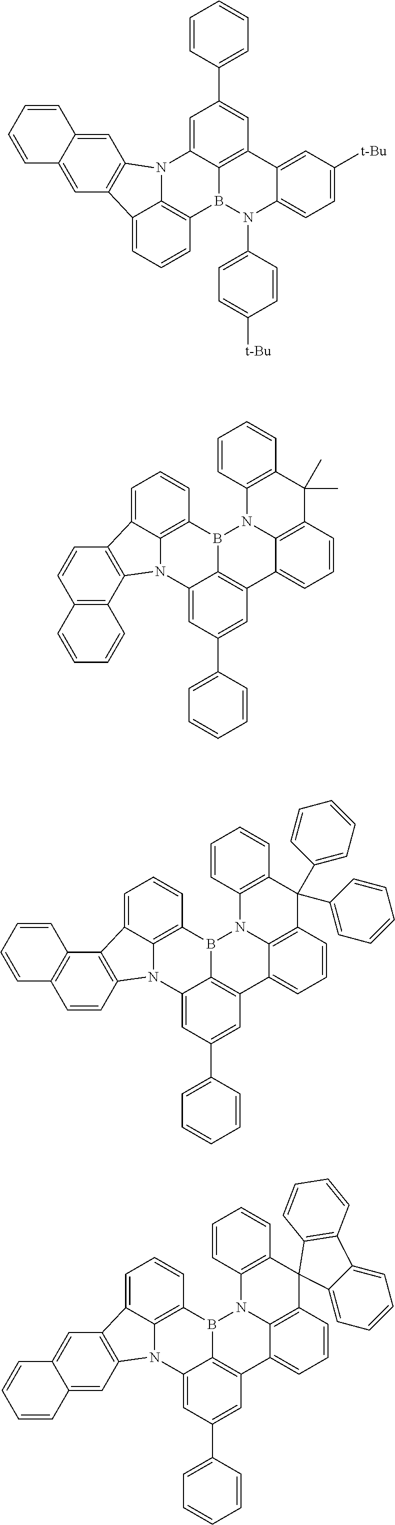 [SMILES: CC(C)(C)c1ccc(N2B3c4c(cc(-c5ccccc5)cc4-n4c5cc6ccccc6cc5c5cccc3c54)-c3cc(C(C)(C)C)ccc32)cc1 ; CC1(C)c2ccccc2N2B3c4c(cc(-c5ccccc5)cc4-n4c5c3cccc5c3ccc5ccccc5c34)-c3cccc1c32 ; c1ccc(-c2cc3c4c(c2)-n2c5ccc6ccccc6c5c5cccc(c52)B4N2c4ccccc4C(c4ccccc4)(c4ccccc4)c4cccc-3c42)cc1 ; c1ccc(-c2cc3c4c(c2)-n2c5cc6ccccc6cc5c5cccc(c52)B4N2c4ccccc4C4(c5ccccc5-c5ccccc54)c4cccc-3c42)cc1] 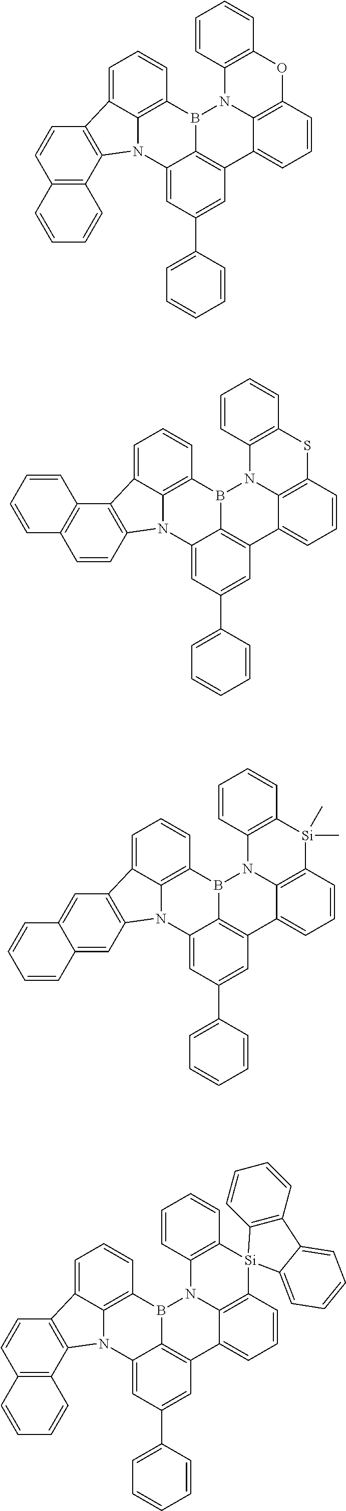 [SMILES: c1ccc(-c2cc3c4c(c2)-n2c5c(cccc5c5ccc6ccccc6c52)B4N2c4ccccc4Oc4cccc-3c42)cc1 ; c1ccc(-c2cc3c4c(c2)-n2c5ccc6ccccc6c5c5cccc(c52)B4N2c4ccccc4Sc4cccc-3c42)cc1 ; C[Si]1(C)c2ccccc2N2B3c4c(cc(-c5ccccc5)cc4-n4c5cc6ccccc6cc5c5cccc3c54)-c3cccc1c32 ; c1ccc(-c2cc3c4c(c2)-n2c5c(cccc5c5ccc6ccccc6c52)B4N2c4ccccc4[Si]4(c5ccccc5-c5ccccc54)c4cccc-3c42)cc1] 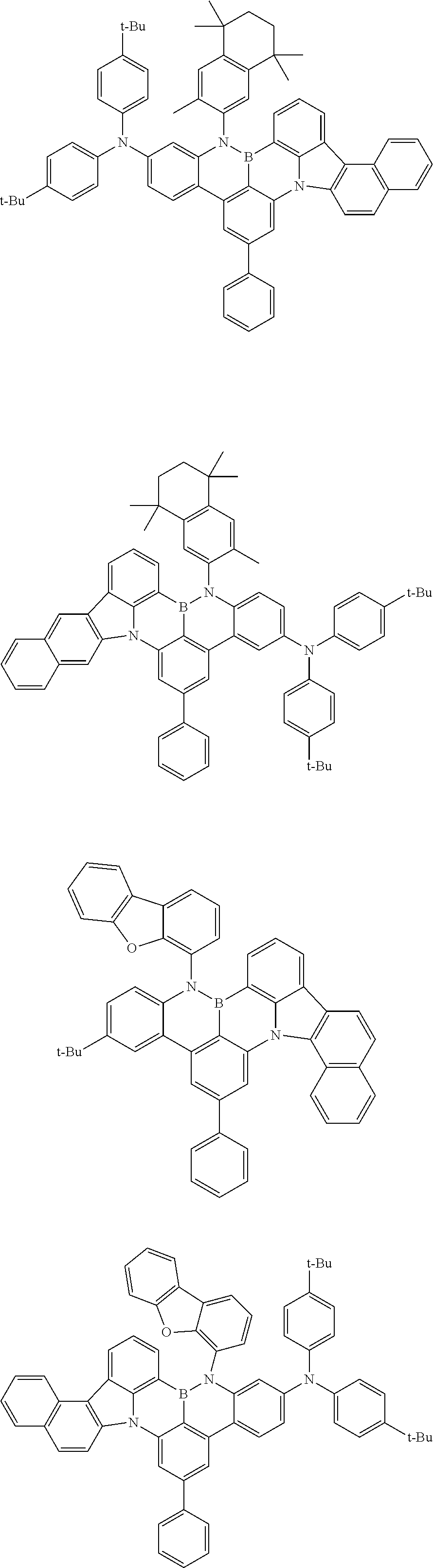 [SMILES: Cc1cc2c(cc1N1B3c4c(cc(-c5ccccc5)cc4-n4c5ccc6ccccc6c5c5cccc3c54)-c3ccc(N(c4ccc(C(C)(C)C)cc4)c4ccc(C(C)(C)C)cc4)cc31)C(C)(C)CCC2(C)C ; Cc1cc2c(cc1N1B3c4c(cc(-c5ccccc5)cc4-n4c5cc6ccccc6cc5c5cccc3c54)-c3cc(N(c4ccc(C(C)(C)C)cc4)c4ccc(C(C)(C)C)cc4)ccc31)C(C)(C)CCC2(C)C ; CC(C)(C)c1ccc2c(c1)-c1cc(-c3ccccc3)cc3c1B(c1cccc4c5ccc6ccccc6c5n-3c14)N2c1cccc2c1oc1ccccc12 ; CC(C)(C)c1ccc(N(c2ccc(C(C)(C)C)cc2)c2ccc3c(c2)N(c2cccc4c2oc2ccccc24)B2c4c-3cc(-c3ccccc3)cc4-n3c4ccc5ccccc5c4c4cccc2c43)cc1] 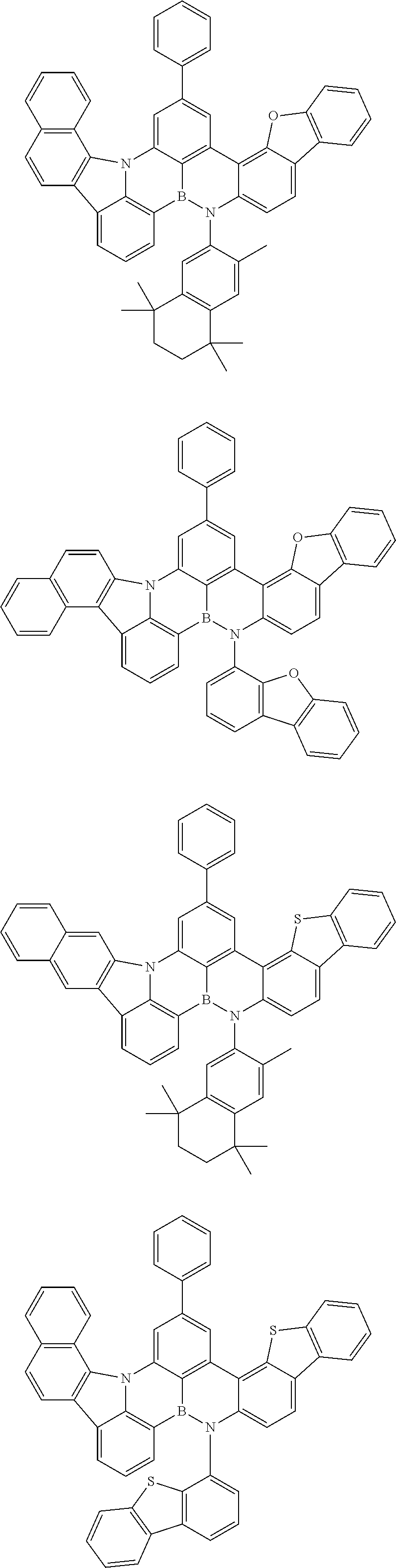 [SMILES: Cc1cc2c(cc1N1B3c4c(cc(-c5ccccc5)cc4-n4c5c3cccc5c3ccc5ccccc5c34)-c3c1ccc1c3oc3ccccc31)C(C)(C)CCC2(C)C ; c1ccc(-c2cc3c4c(c2)-n2c5ccc6ccccc6c5c5cccc(c52)B4N(c2cccc4c2oc2ccccc24)c2ccc4c(oc5ccccc54)c2-3)cc1 ; Cc1cc2c(cc1N1B3c4c(cc(-c5ccccc5)cc4-n4c5cc6ccccc6cc5c5cccc3c54)-c3c1ccc1c3sc3ccccc31)C(C)(C)CCC2(C)C ; c1ccc(-c2cc3c4c(c2)-n2c5c(cccc5c5ccc6ccccc6c52)B4N(c2cccc4c2sc2ccccc24)c2ccc4c(sc5ccccc54)c2-3)cc1] 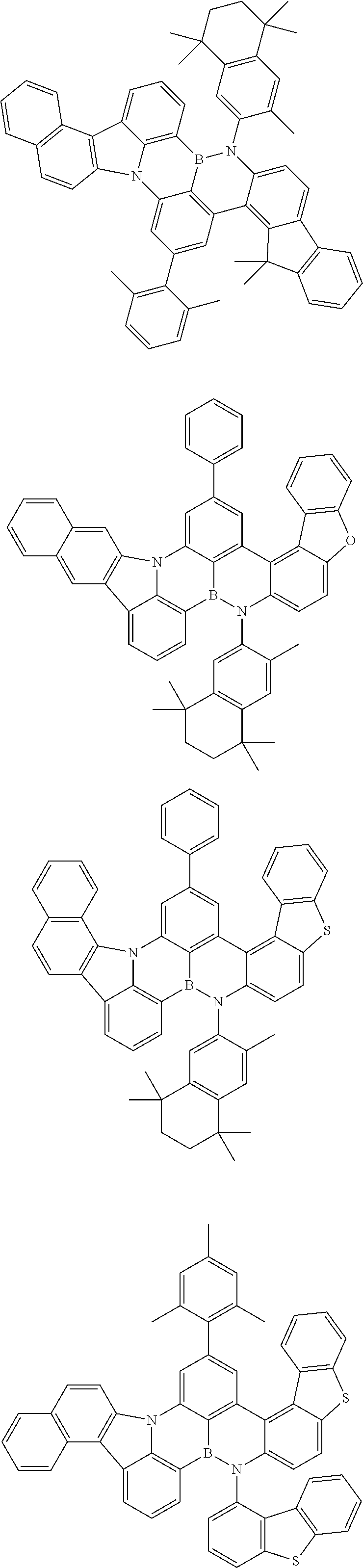 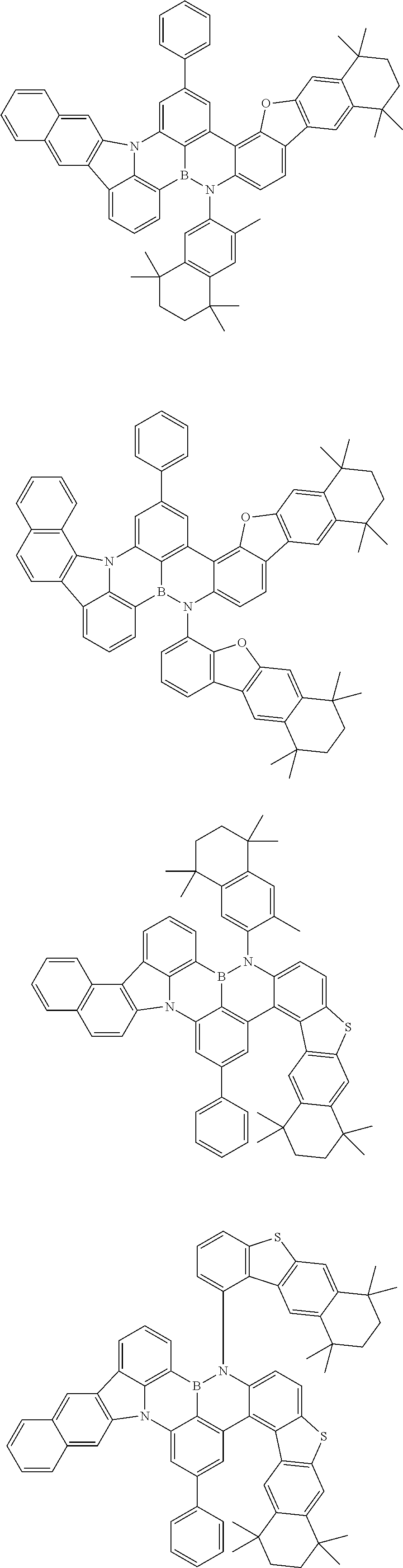 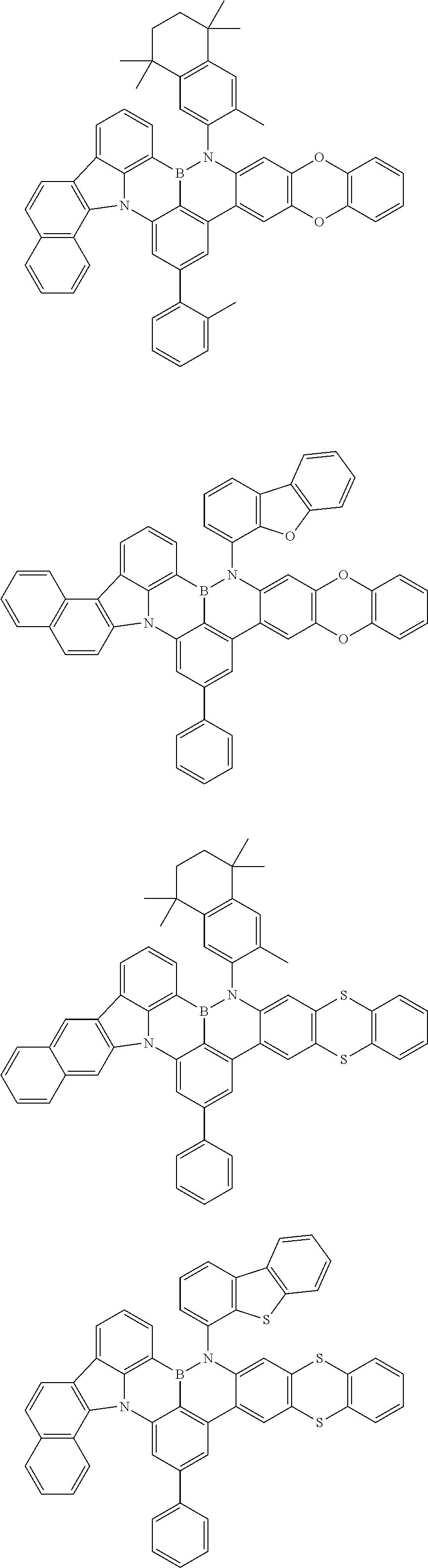 [SMILES: Cc1ccccc1-c1cc2c3c(c1)-n1c4c(cccc4c4ccc5ccccc5c41)B3N(c1cc3c(cc1C)C(C)(C)CCC3(C)C)c1cc3c(cc1-2)Oc1ccccc1O3 ; c1ccc(-c2cc3c4c(c2)-n2c5ccc6ccccc6c5c5cccc(c52)B4N(c2cccc4c2oc2ccccc24)c2cc4c(cc2-3)Oc2ccccc2O4)cc1 ; Cc1cc2c(cc1N1B3c4c(cc(-c5ccccc5)cc4-n4c5cc6ccccc6cc5c5cccc3c54)-c3cc4c(cc31)Sc1ccccc1S4)C(C)(C)CCC2(C)C ; c1ccc(-c2cc3c4c(c2)-n2c5c(cccc5c5ccc6ccccc6c52)B4N(c2cccc4c2sc2ccccc24)c2cc4c(cc2-3)Sc2ccccc2S4)cc1] 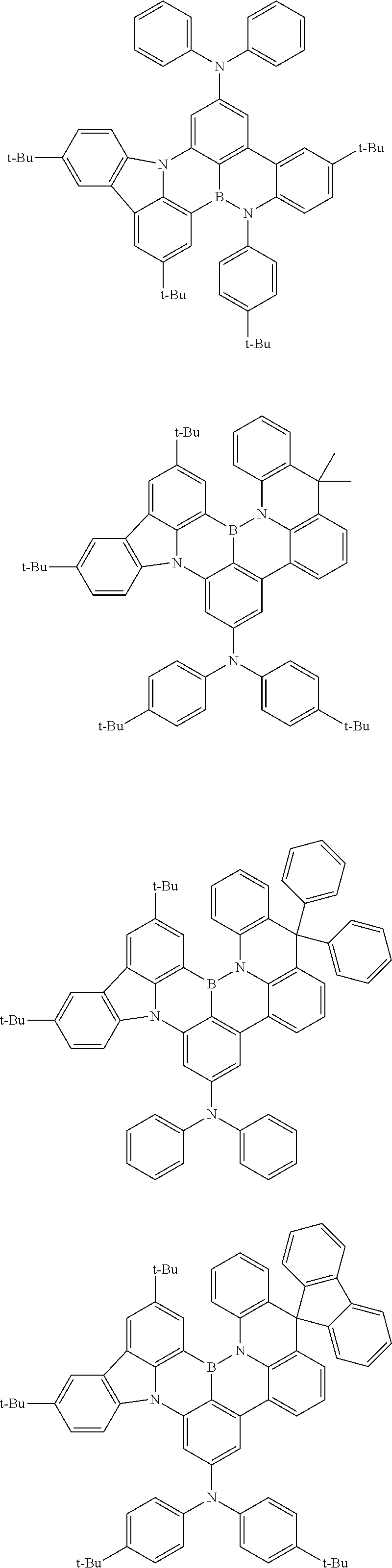 [SMILES: CC(C)(C)c1ccc(N2B3c4c(cc(N(c5ccccc5)c5ccccc5)cc4-n4c5ccc(C(C)(C)C)cc5c5cc(C(C)(C)C)cc3c54)-c3cc(C(C)(C)C)ccc32)cc1 ; CC(C)(C)c1ccc(N(c2ccc(C(C)(C)C)cc2)c2cc3c4c(c2)-n2c5ccc(C(C)(C)C)cc5c5cc(C(C)(C)C)cc(c52)B4N2c4ccccc4C(C)(C)c4cccc-3c42)cc1 ; CC(C)(C)c1ccc2c(c1)c1cc(C(C)(C)C)cc3c1n2-c1cc(N(c2ccccc2)c2ccccc2)cc2c1B3N1c3ccccc3C(c3ccccc3)(c3ccccc3)c3cccc-2c31 ; CC(C)(C)c1ccc(N(c2ccc(C(C)(C)C)cc2)c2cc3c4c(c2)-n2c5ccc(C(C)(C)C)cc5c5cc(C(C)(C)C)cc(c52)B4N2c4ccccc4C4(c5ccccc5-c5ccccc54)c4cccc-3c42)cc1] 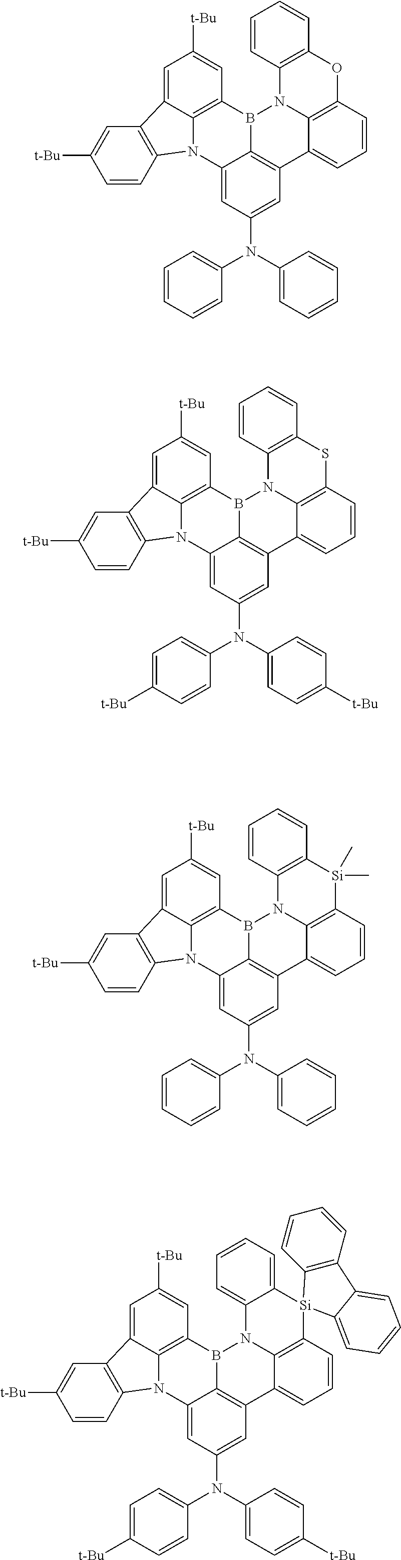 [SMILES: CC(C)(C)c1ccc2c(c1)c1cc(C(C)(C)C)cc3c1n2-c1cc(N(c2ccccc2)c2ccccc2)cc2c1B3N1c3ccccc3Oc3cccc-2c31 ; CC(C)(C)c1ccc(N(c2ccc(C(C)(C)C)cc2)c2cc3c4c(c2)-n2c5ccc(C(C)(C)C)cc5c5cc(C(C)(C)C)cc(c52)B4N2c4ccccc4Sc4cccc-3c42)cc1 ; CC(C)(C)c1ccc2c(c1)c1cc(C(C)(C)C)cc3c1n2-c1cc(N(c2ccccc2)c2ccccc2)cc2c1B3N1c3ccccc3[Si](C)(C)c3cccc-2c31 ; CC(C)(C)c1ccc(N(c2ccc(C(C)(C)C)cc2)c2cc3c4c(c2)-n2c5ccc(C(C)(C)C)cc5c5cc(C(C)(C)C)cc(c52)B4N2c4ccccc4[Si]4(c5ccccc5-c5ccccc54)c4cccc-3c42)cc1] 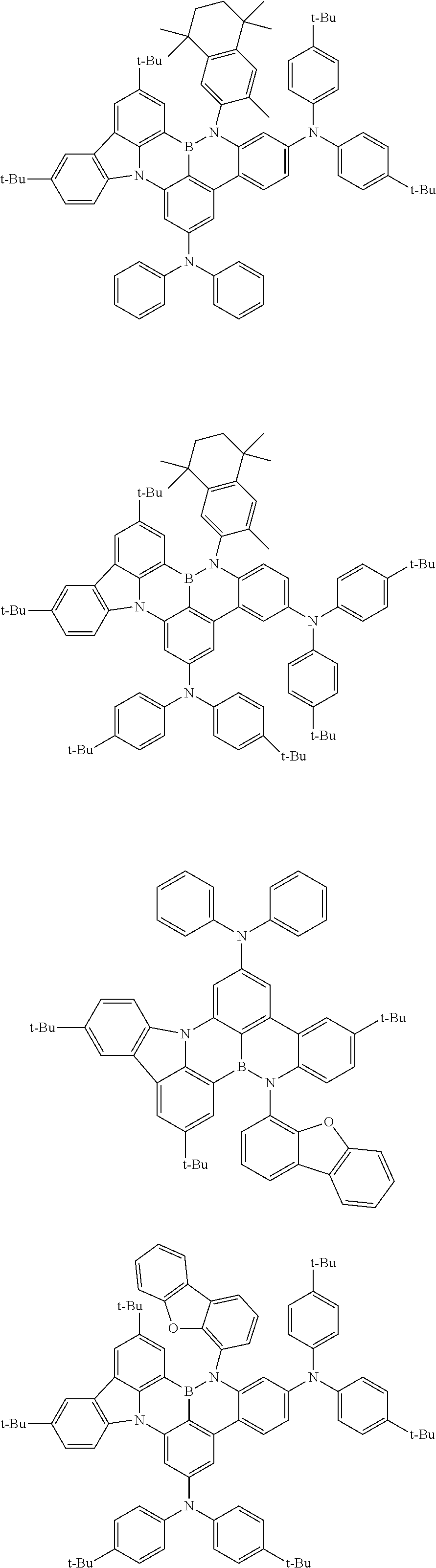 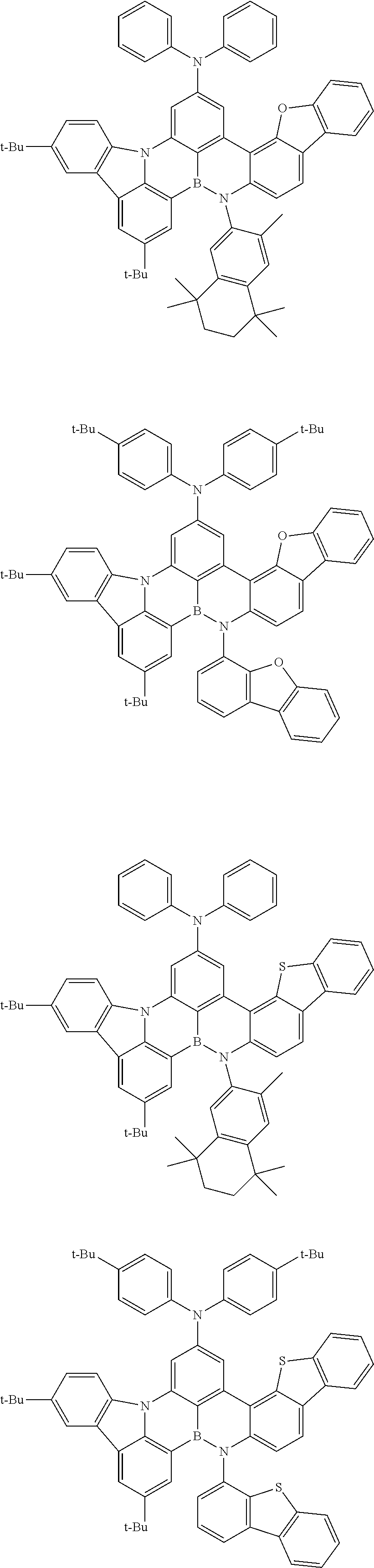 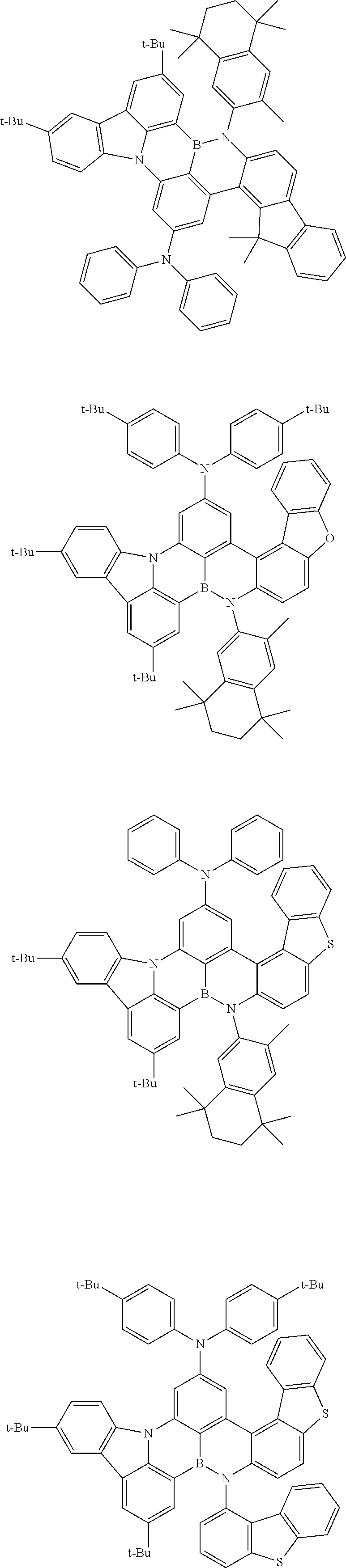 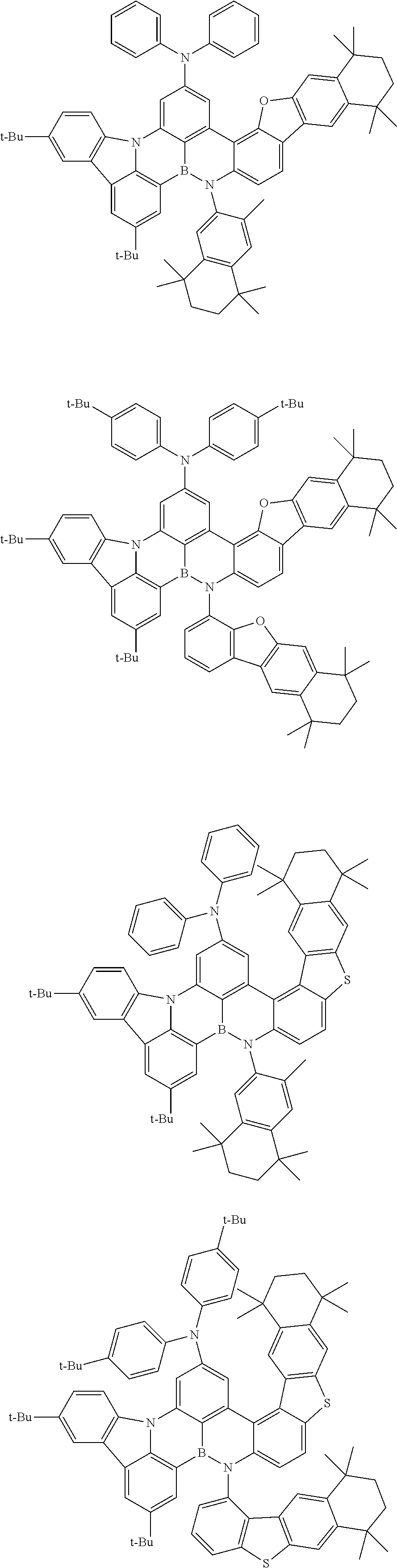 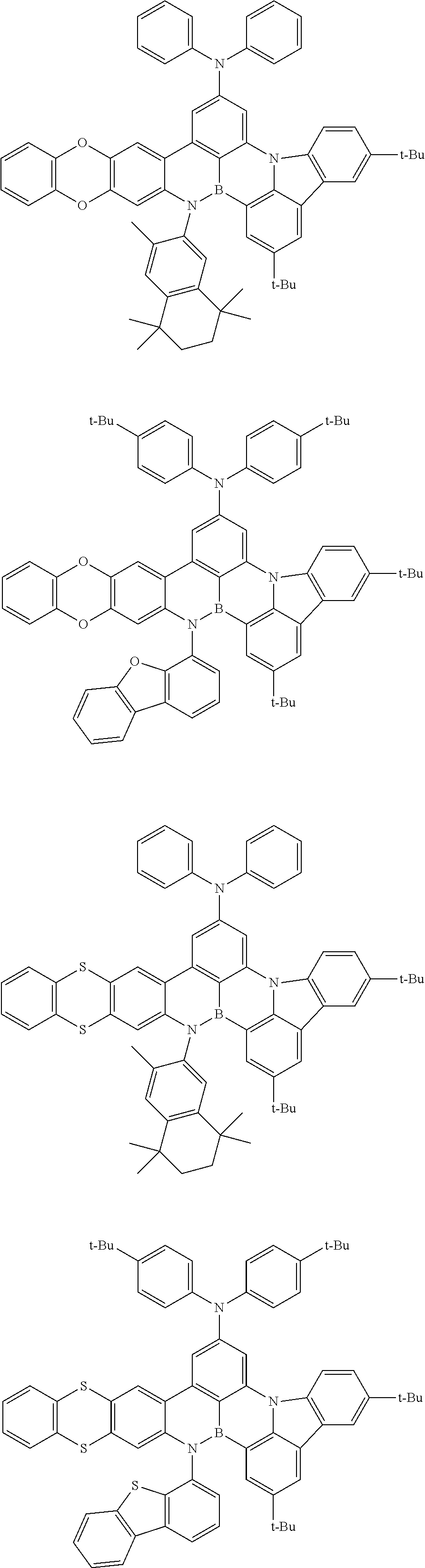 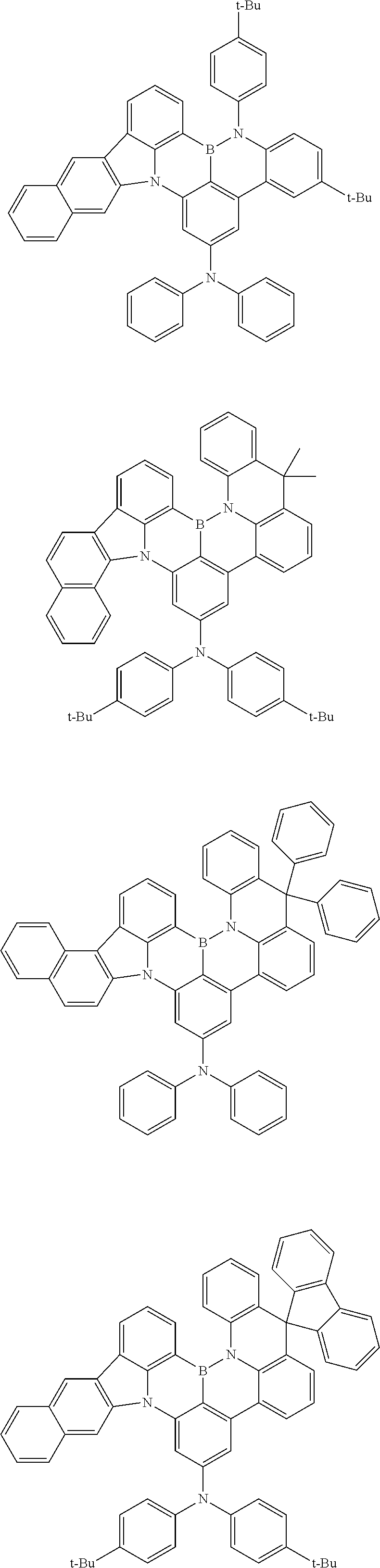 [SMILES: CC(C)(C)c1ccc(N2B3c4c(cc(N(c5ccccc5)c5ccccc5)cc4-n4c5cc6ccccc6cc5c5cccc3c54)-c3cc(C(C)(C)C)ccc32)cc1 ; CC(C)(C)c1ccc(N(c2ccc(C(C)(C)C)cc2)c2cc3c4c(c2)-n2c5c(cccc5c5ccc6ccccc6c52)B4N2c4ccccc4C(C)(C)c4cccc-3c42)cc1 ; c1ccc(N(c2ccccc2)c2cc3c4c(c2)-n2c5ccc6ccccc6c5c5cccc(c52)B4N2c4ccccc4C(c4ccccc4)(c4ccccc4)c4cccc-3c42)cc1 ; CC(C)(C)c1ccc(N(c2ccc(C(C)(C)C)cc2)c2cc3c4c(c2)-n2c5cc6ccccc6cc5c5cccc(c52)B4N2c4ccccc4C4(c5ccccc5-c5ccccc54)c4cccc-3c42)cc1] 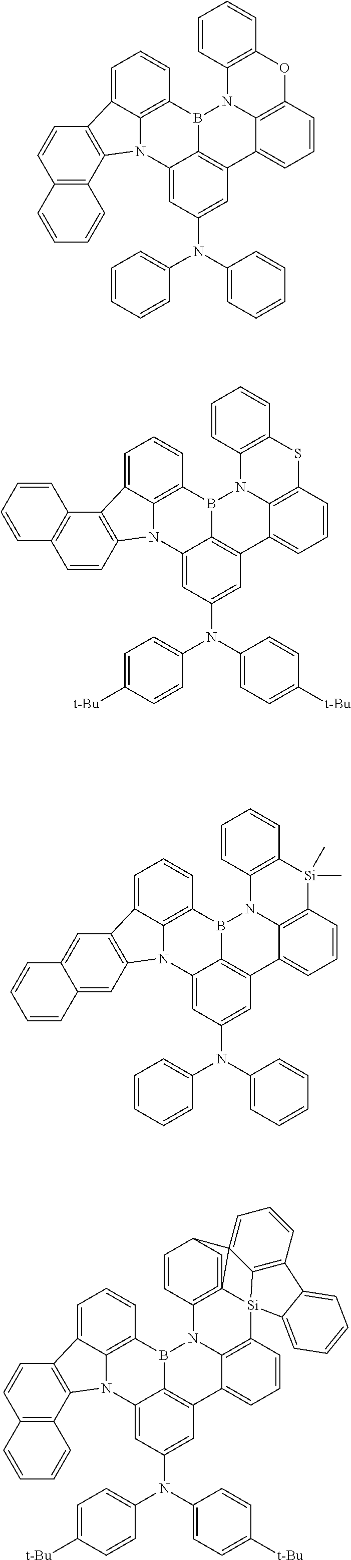 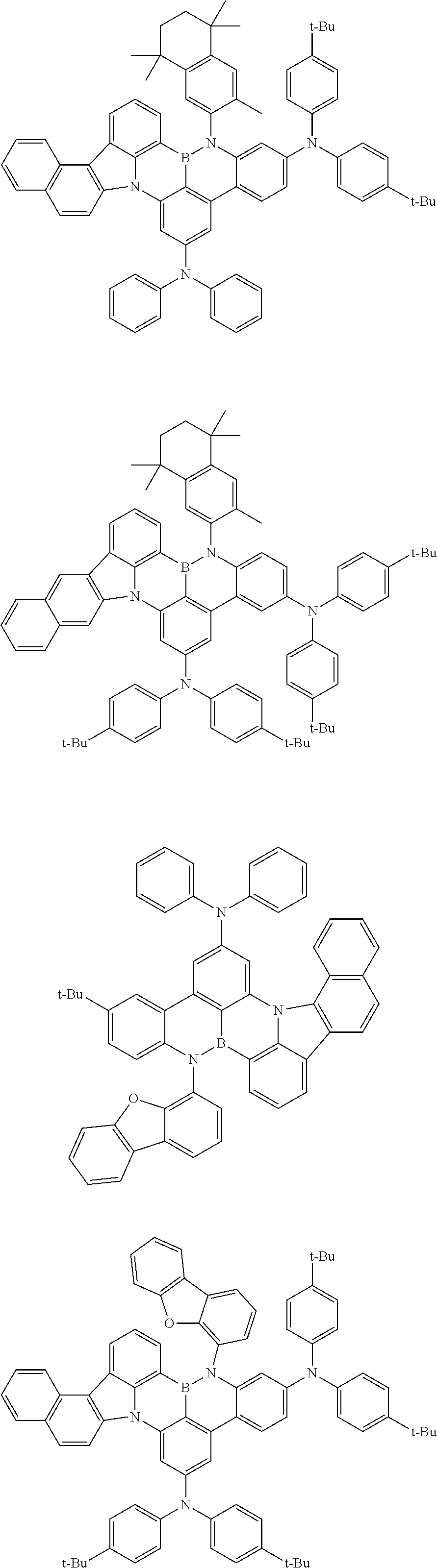 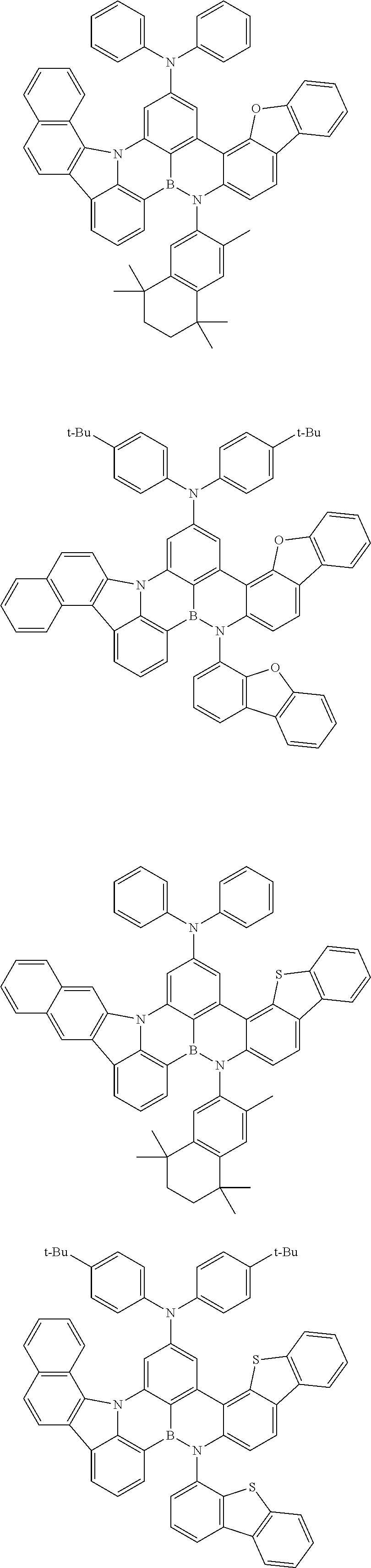 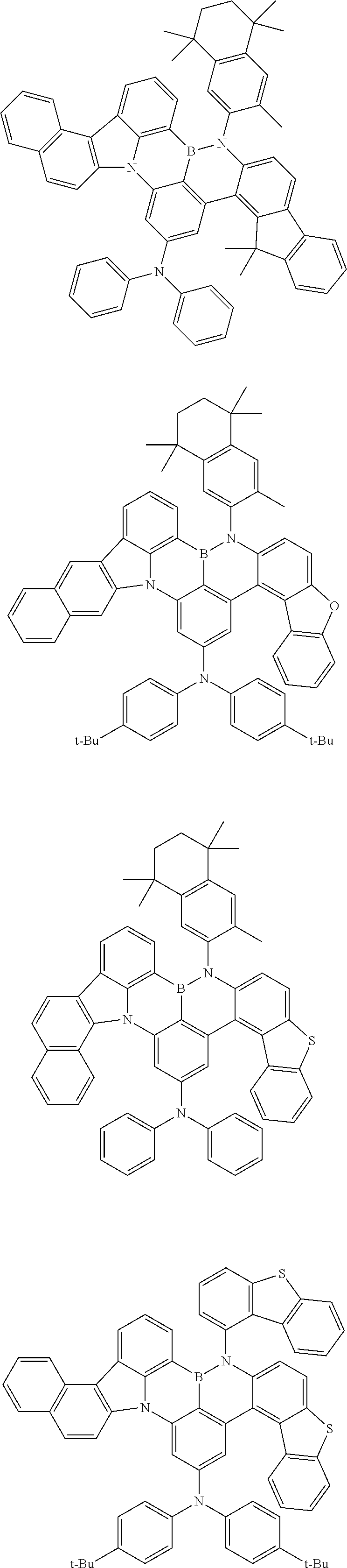 [SMILES: Cc1cc2c(cc1N1B3c4c(cc(N(c5ccccc5)c5ccccc5)cc4-n4c5ccc6ccccc6c5c5cccc3c54)-c3c1ccc1c3C(C)(C)c3ccccc3-1)C(C)(C)CCC2(C)C ; Cc1cc2c(cc1N1B3c4c(cc(N(c5ccc(C(C)(C)C)cc5)c5ccc(C(C)(C)C)cc5)cc4-n4c5cc6ccccc6cc5c5cccc3c54)-c3c1ccc1oc4ccccc4c31)C(C)(C)CCC2(C)C ; Cc1cc2c(cc1N1B3c4c(cc(N(c5ccccc5)c5ccccc5)cc4-n4c5c3cccc5c3ccc5ccccc5c34)-c3c1ccc1sc4ccccc4c31)C(C)(C)CCC2(C)C ; CC(C)(C)c1ccc(N(c2ccc(C(C)(C)C)cc2)c2cc3c4c(c2)-n2c5ccc6ccccc6c5c5cccc(c52)B4N(c2cccc4sc5ccccc5c24)c2ccc4sc5ccccc5c4c2-3)cc1] 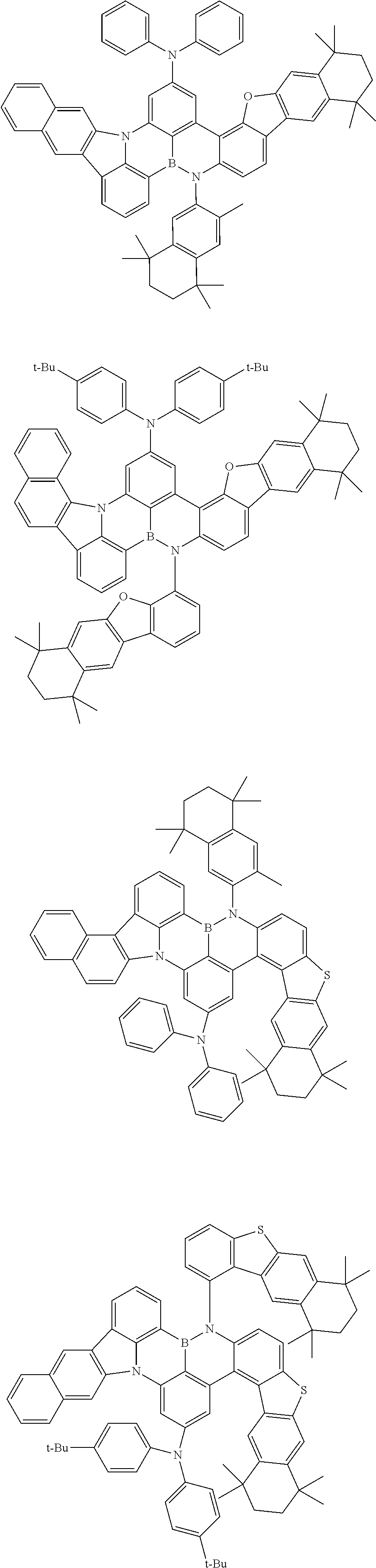 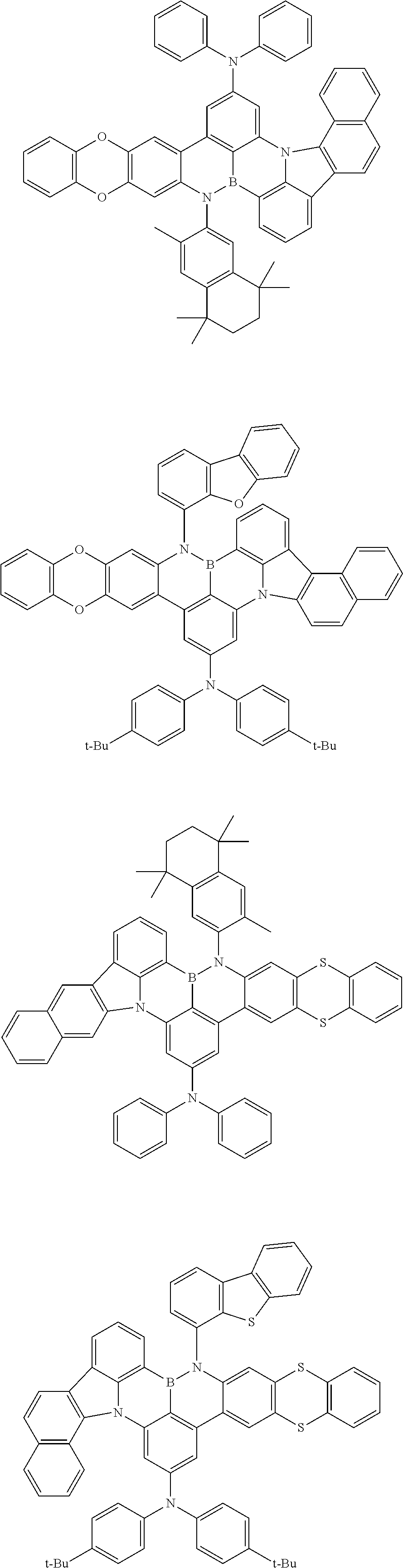 [SMILES: Cc1cc2c(cc1N1B3c4c(cc(N(c5ccccc5)c5ccccc5)cc4-n4c5c3cccc5c3ccc5ccccc5c34)-c3cc4c(cc31)Oc1ccccc1O4)C(C)(C)CCC2(C)C ; CC(C)(C)c1ccc(N(c2ccc(C(C)(C)C)cc2)c2cc3c4c(c2)-n2c5ccc6ccccc6c5c5cccc(c52)B4N(c2cccc4c2oc2ccccc24)c2cc4c(cc2-3)Oc2ccccc2O4)cc1 ; Cc1cc2c(cc1N1B3c4c(cc(N(c5ccccc5)c5ccccc5)cc4-n4c5cc6ccccc6cc5c5cccc3c54)-c3cc4c(cc31)Sc1ccccc1S4)C(C)(C)CCC2(C)C ; CC(C)(C)c1ccc(N(c2ccc(C(C)(C)C)cc2)c2cc3c4c(c2)-n2c5c(cccc5c5ccc6ccccc6c52)B4N(c2cccc4c2sc2ccccc24)c2cc4c(cc2-3)Sc2ccccc2S4)cc1] 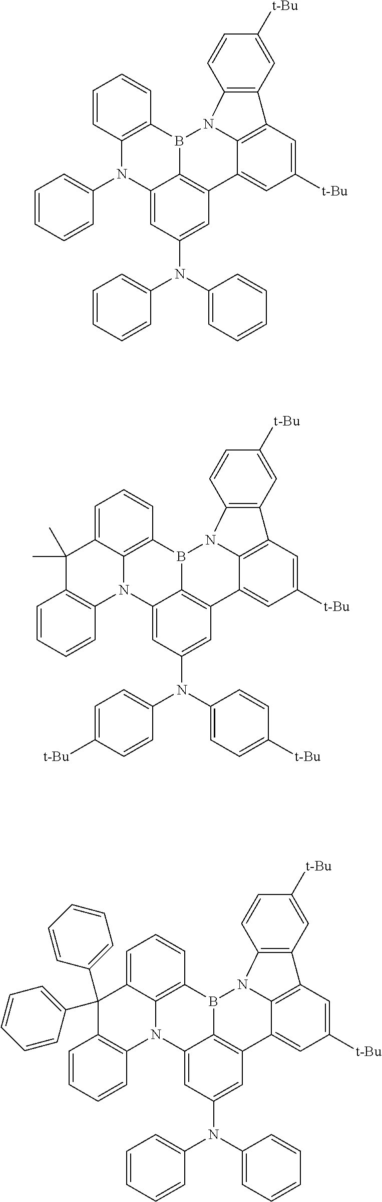 [SMILES: CC(C)(C)c1ccc2c(c1)c1cc(C(C)(C)C)cc3c1n2B1c2ccccc2N(c2ccccc2)c2cc(N(c4ccccc4)c4ccccc4)cc-3c21 ; CC(C)(C)c1ccc(N(c2ccc(C(C)(C)C)cc2)c2cc3c4c(c2)N2c5ccccc5C(C)(C)c5cccc(c52)B4n2c4ccc(C(C)(C)C)cc4c4cc(C(C)(C)C)cc-3c42)cc1 ; CC(C)(C)c1ccc2c(c1)c1cc(C(C)(C)C)cc3c1n2B1c2cccc4c2N(c2ccccc2C4(c2ccccc2)c2ccccc2)c2cc(N(c4ccccc4)c4ccccc4)cc-3c21] 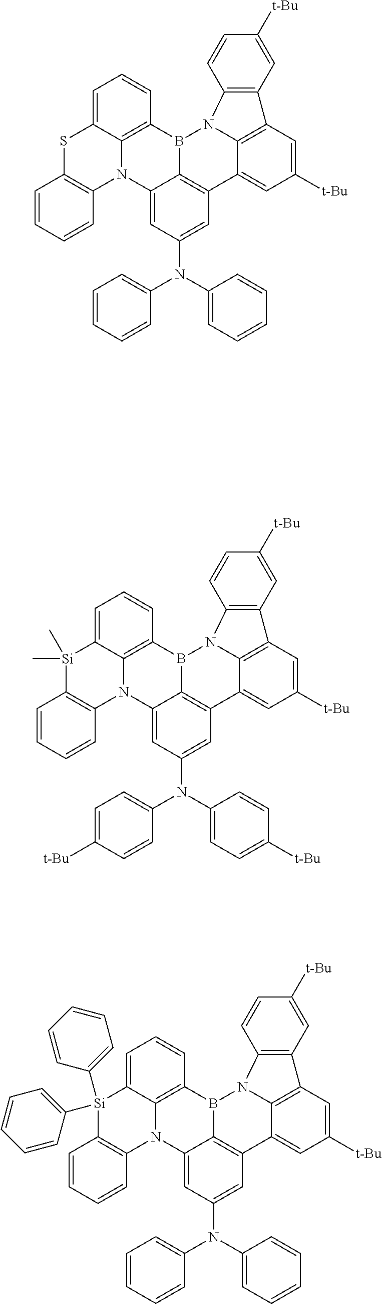 [SMILES: CC(C)(C)c1ccc2c(c1)c1cc(C(C)(C)C)cc3c1n2B1c2cccc4c2N(c2ccccc2S4)c2cc(N(c4ccccc4)c4ccccc4)cc-3c21 ; CC(C)(C)c1ccc(N(c2ccc(C(C)(C)C)cc2)c2cc3c4c(c2)N2c5ccccc5[Si](C)(C)c5cccc(c52)B4n2c4ccc(C(C)(C)C)cc4c4cc(C(C)(C)C)cc-3c42)cc1 ; CC(C)(C)c1ccc2c(c1)c1cc(C(C)(C)C)cc3c1n2B1c2cccc4c2N(c2ccccc2[Si]4(c2ccccc2)c2ccccc2)c2cc(N(c4ccccc4)c4ccccc4)cc-3c21] 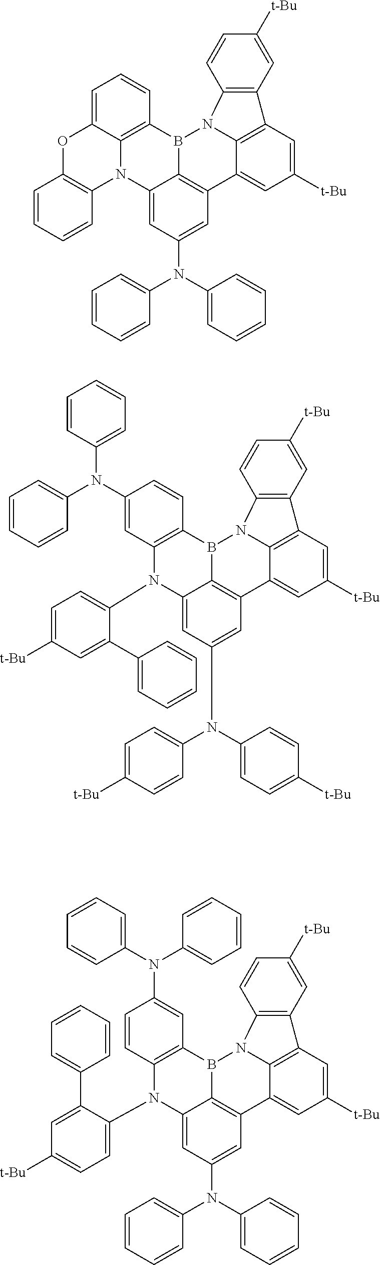 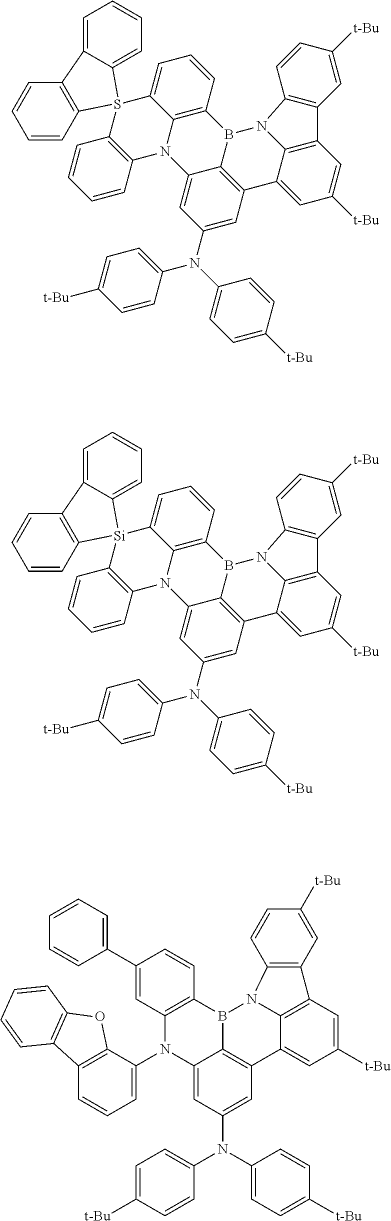 [SMILES: CC(C)(C)c1ccc(N(c2ccc(C(C)(C)C)cc2)c2cc3c4c(c2)N2c5ccccc5S5(c6ccccc6-c6ccccc65)c5cccc(c52)B4n2c4ccc(C(C)(C)C)cc4c4cc(C(C)(C)C)cc-3c42)cc1 ; CC(C)(C)c1ccc(N(c2ccc(C(C)(C)C)cc2)c2cc3c4c(c2)N2c5ccccc5[Si]5(c6ccccc6-c6ccccc65)c5cccc(c52)B4n2c4ccc(C(C)(C)C)cc4c4cc(C(C)(C)C)cc-3c42)cc1 ; CC(C)(C)c1ccc(N(c2ccc(C(C)(C)C)cc2)c2cc3c4c(c2)N(c2cccc5c2oc2ccccc25)c2cc(-c5ccccc5)ccc2B4n2c4ccc(C(C)(C)C)cc4c4cc(C(C)(C)C)cc-3c42)cc1] 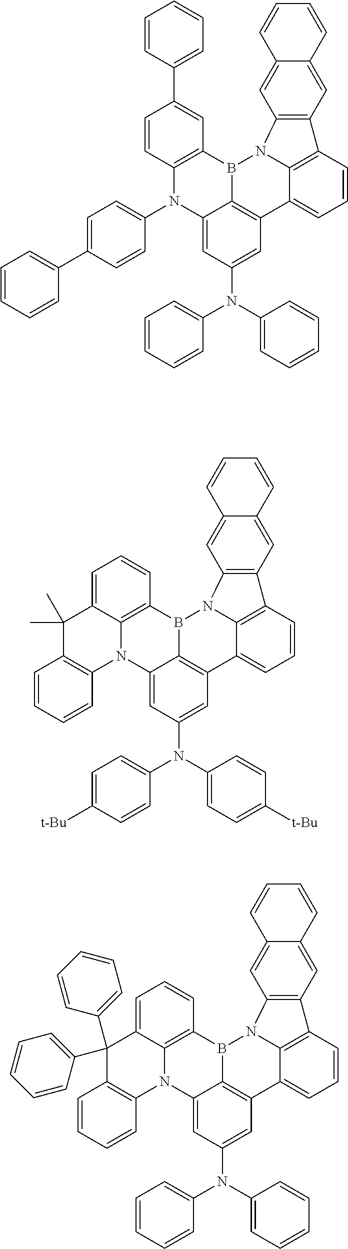 [SMILES: c1ccc(-c2ccc(N3c4ccc(-c5ccccc5)cc4B4c5c(cc(N(c6ccccc6)c6ccccc6)cc53)-c3cccc5c6cc7ccccc7cc6n4c35)cc2)cc1 ; CC(C)(C)c1ccc(N(c2ccc(C(C)(C)C)cc2)c2cc3c4c(c2)N2c5ccccc5C(C)(C)c5cccc(c52)B4n2c4cc5ccccc5cc4c4cccc-3c42)cc1 ; c1ccc(N(c2ccccc2)c2cc3c4c(c2)N2c5ccccc5C(c5ccccc5)(c5ccccc5)c5cccc(c52)B4n2c4cc5ccccc5cc4c4cccc-3c42)cc1] 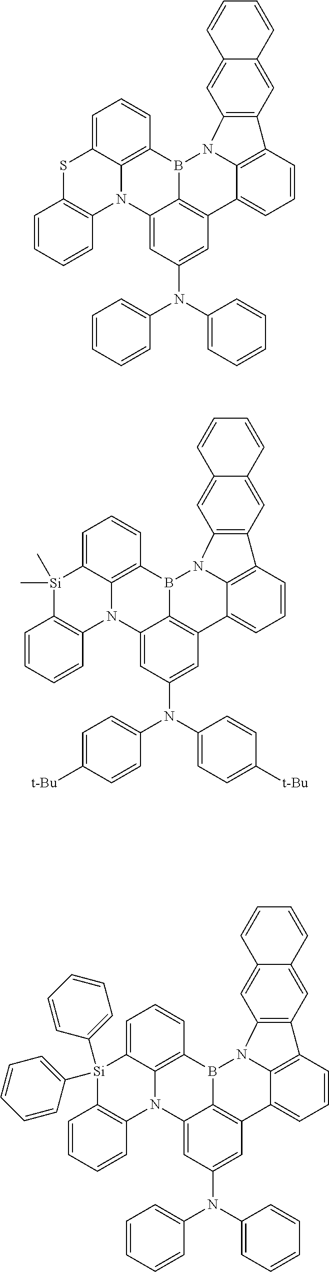 [SMILES: c1ccc(N(c2ccccc2)c2cc3c4c(c2)N2c5ccccc5Sc5cccc(c52)B4n2c4cc5ccccc5cc4c4cccc-3c42)cc1 ; CC(C)(C)c1ccc(N(c2ccc(C(C)(C)C)cc2)c2cc3c4c(c2)N2c5ccccc5[Si](C)(C)c5cccc(c52)B4n2c4cc5ccccc5cc4c4cccc-3c42)cc1 ; c1ccc(N(c2ccccc2)c2cc3c4c(c2)N2c5ccccc5[Si](c5ccccc5)(c5ccccc5)c5cccc(c52)B4n2c4cc5ccccc5cc4c4cccc-3c42)cc1] 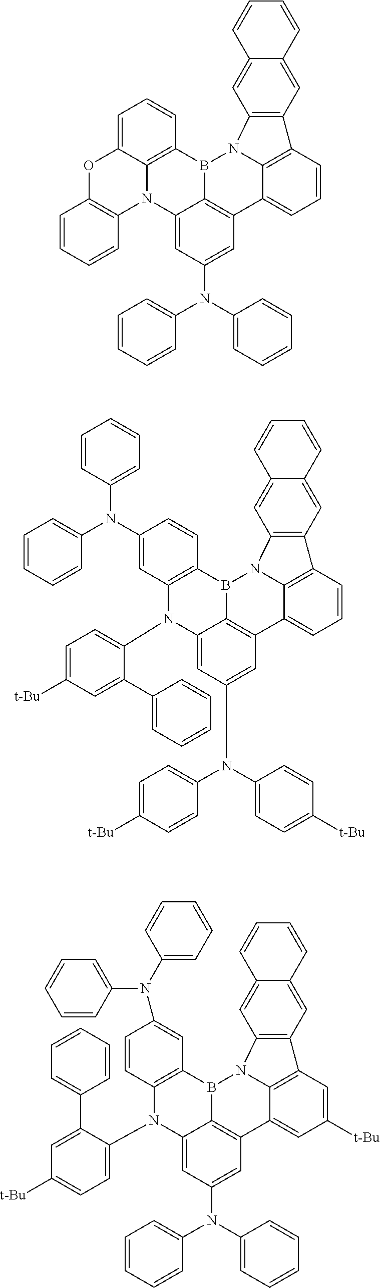 [SMILES: c1ccc(N(c2ccccc2)c2cc3c4c(c2)N2c5ccccc5Oc5cccc(c52)B4n2c4cc5ccccc5cc4c4cccc-3c42)cc1 ; CC(C)(C)c1ccc(N(c2ccc(C(C)(C)C)cc2)c2cc3c4c(c2)N(c2ccc(C(C)(C)C)cc2-c2ccccc2)c2cc(N(c5ccccc5)c5ccccc5)ccc2B4n2c4cc5ccccc5cc4c4cccc-3c42)cc1 ; CC(C)(C)c1ccc(N2c3ccc(N(c4ccccc4)c4ccccc4)cc3B3c4c(cc(N(c5ccccc5)c5ccccc5)cc42)-c2cc(C(C)(C)C)cc4c5cc6ccccc6cc5n3c24)c(-c2ccccc2)c1] 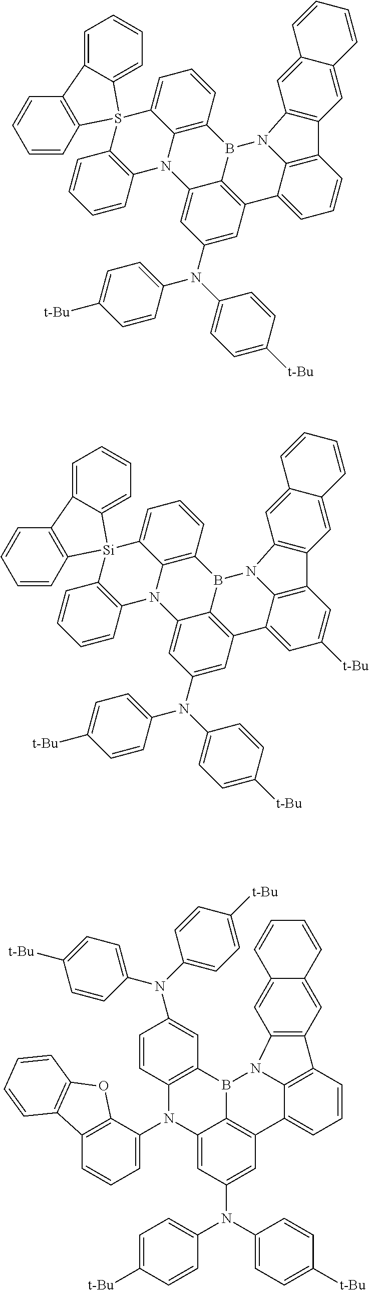 [SMILES: CC(C)(C)c1ccc(N(c2ccc(C(C)(C)C)cc2)c2cc3c4c(c2)N2c5ccccc5S5(c6ccccc6-c6ccccc65)c5cccc(c52)B4n2c4cc5ccccc5cc4c4cccc-3c42)cc1 ; CC(C)(C)c1ccc(N(c2ccc(C(C)(C)C)cc2)c2cc3c4c(c2)N2c5ccccc5[Si]5(c6ccccc6-c6ccccc65)c5cccc(c52)B4n2c4cc5ccccc5cc4c4cc(C(C)(C)C)cc-3c42)cc1 ; CC(C)(C)c1ccc(N(c2ccc(C(C)(C)C)cc2)c2ccc3c(c2)B2c4c(cc(N(c5ccc(C(C)(C)C)cc5)c5ccc(C(C)(C)C)cc5)cc4N3c3cccc4c3oc3ccccc34)-c3cccc4c5cc6ccccc6cc5n2c34)cc1] 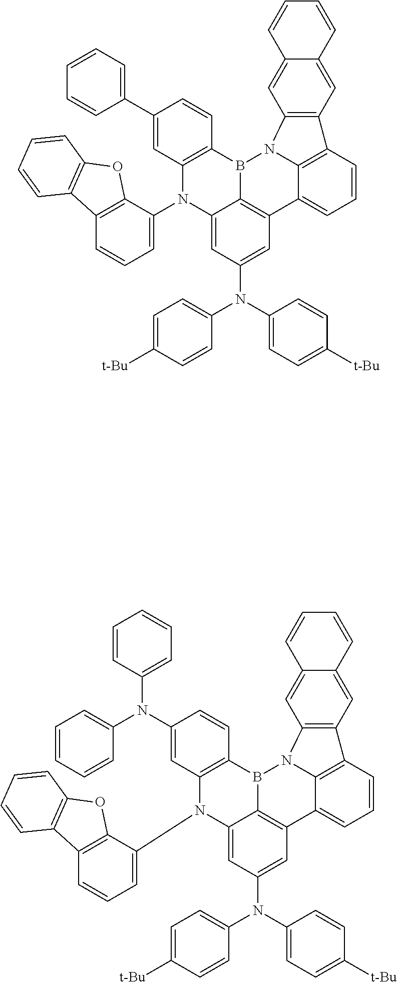 [SMILES: CC(C)(C)c1ccc(N(c2ccc(C(C)(C)C)cc2)c2cc3c4c(c2)N(c2cccc5c2oc2ccccc25)c2cc(-c5ccccc5)ccc2B4n2c4cc5ccccc5cc4c4cccc-3c42)cc1 ; CC(C)(C)c1ccc(N(c2ccc(C(C)(C)C)cc2)c2cc3c4c(c2)N(c2cccc5c2oc2ccccc25)c2cc(N(c5ccccc5)c5ccccc5)ccc2B4n2c4cc5ccccc5cc4c4cccc-3c42)cc1] 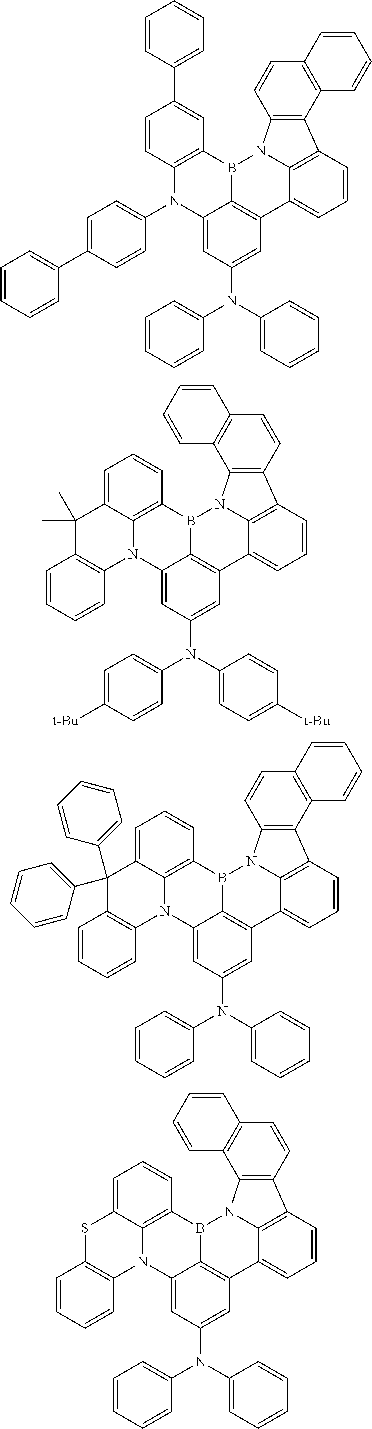 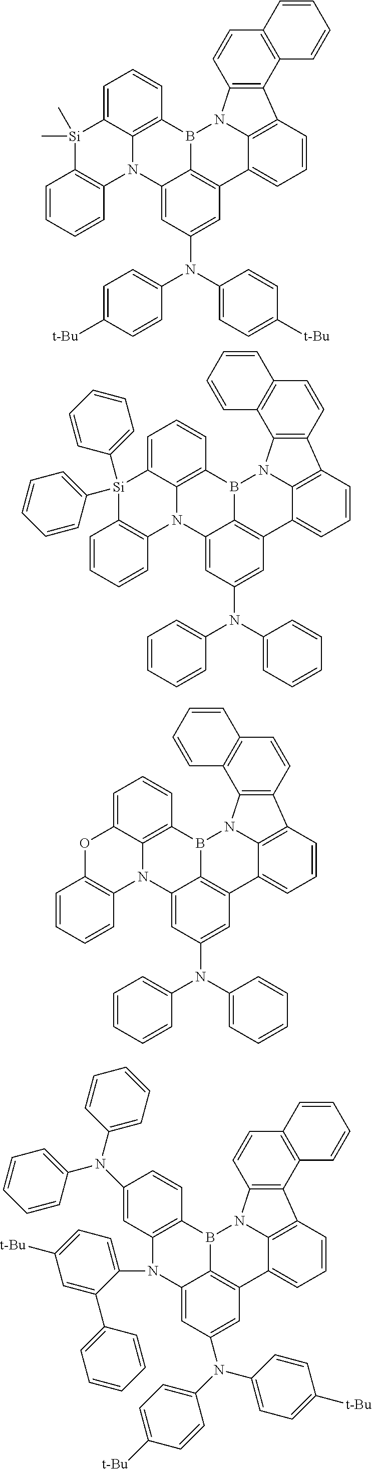 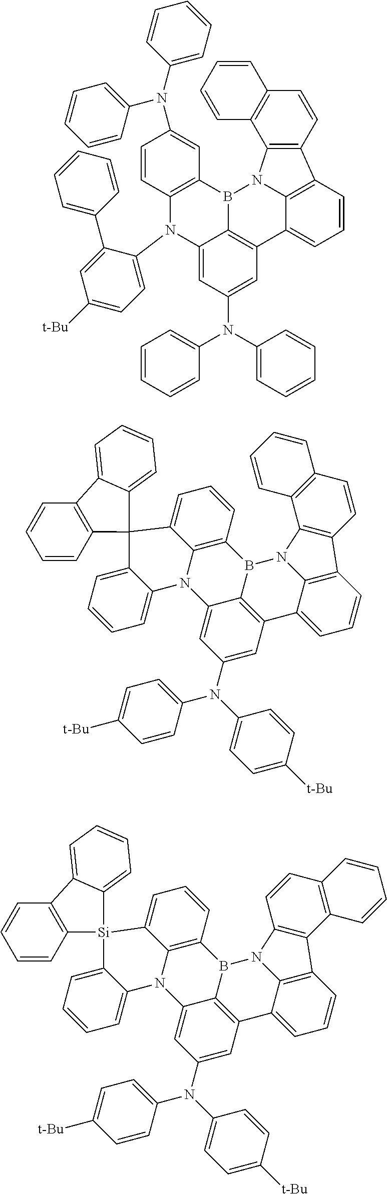 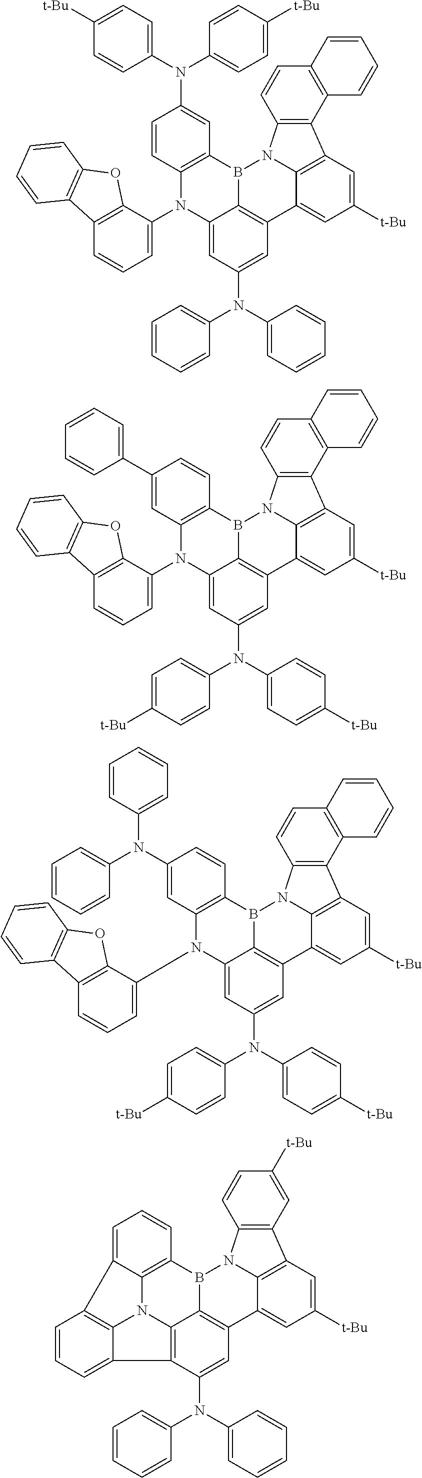 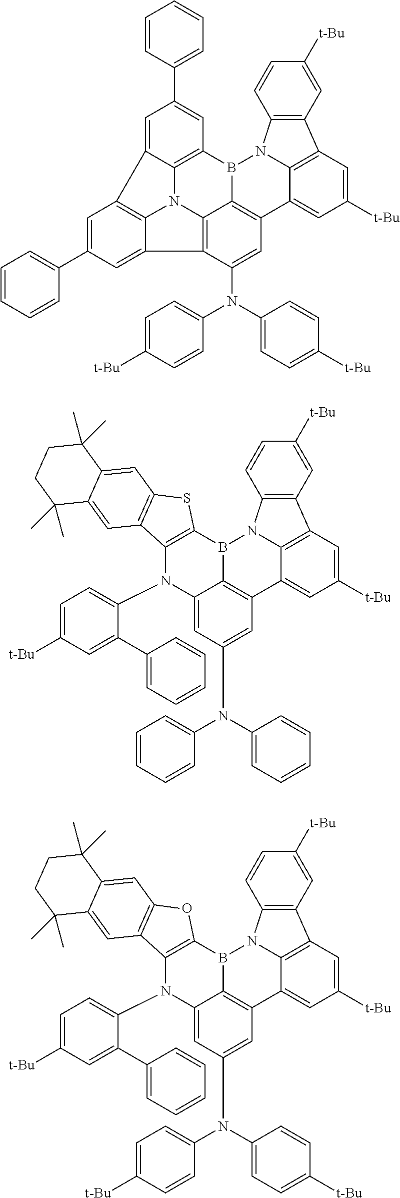 [SMILES: CC(C)(C)c1ccc(N(c2ccc(C(C)(C)C)cc2)c2cc3c4c5c2c2cc(-c6ccccc6)cc6c7cc(-c8ccccc8)cc(c7n5c62)B4n2c4ccc(C(C)(C)C)cc4c4cc(C(C)(C)C)cc-3c42)cc1 ; CC(C)(C)c1ccc(N2c3cc(N(c4ccccc4)c4ccccc4)cc4c3B(c3sc5cc6c(cc5c32)C(C)(C)CCC6(C)C)n2c3ccc(C(C)(C)C)cc3c3cc(C(C)(C)C)cc-4c32)c(-c2ccccc2)c1 ; CC(C)(C)c1ccc(N(c2ccc(C(C)(C)C)cc2)c2cc3c4c(c2)N(c2ccc(C(C)(C)C)cc2-c2ccccc2)c2c(oc5cc6c(cc25)C(C)(C)CCC6(C)C)B4n2c4ccc(C(C)(C)C)cc4c4cc(C(C)(C)C)cc-3c42)cc1] 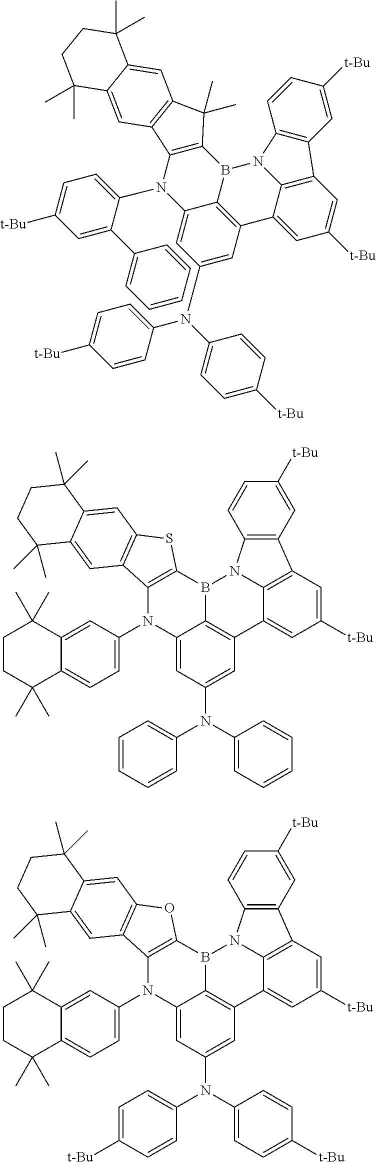 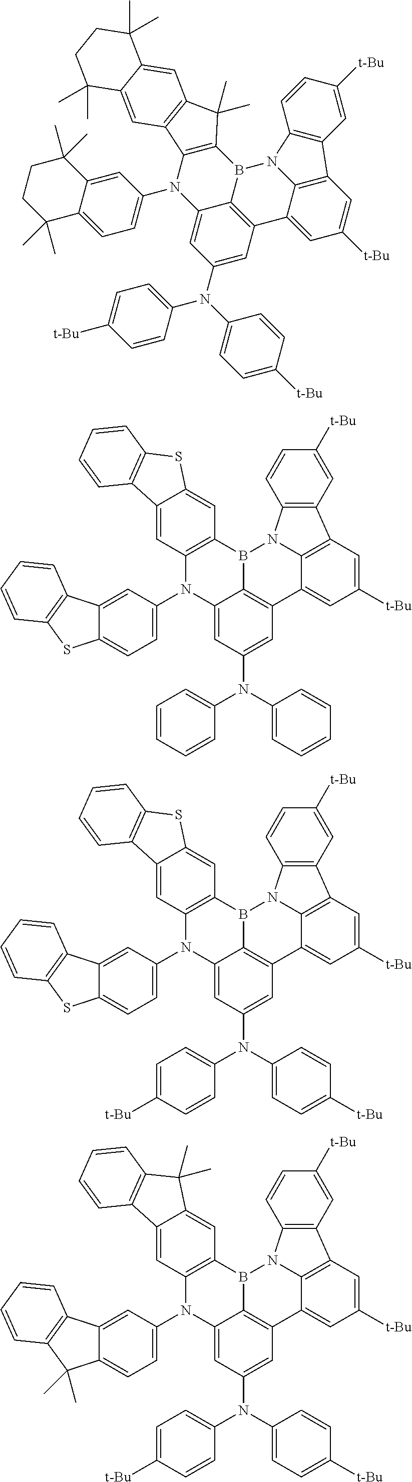 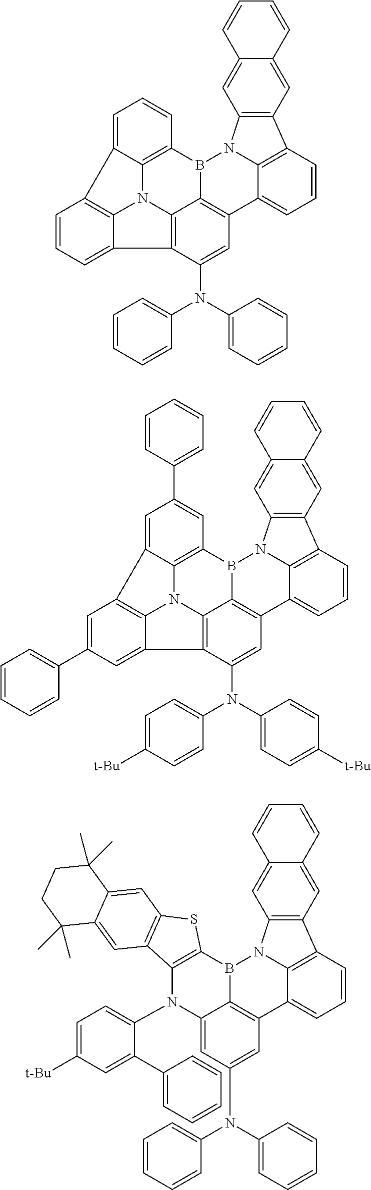 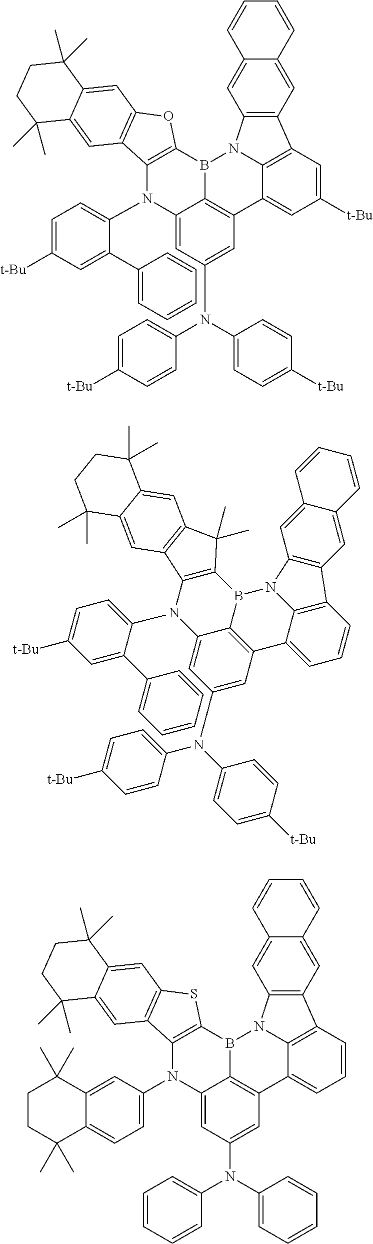 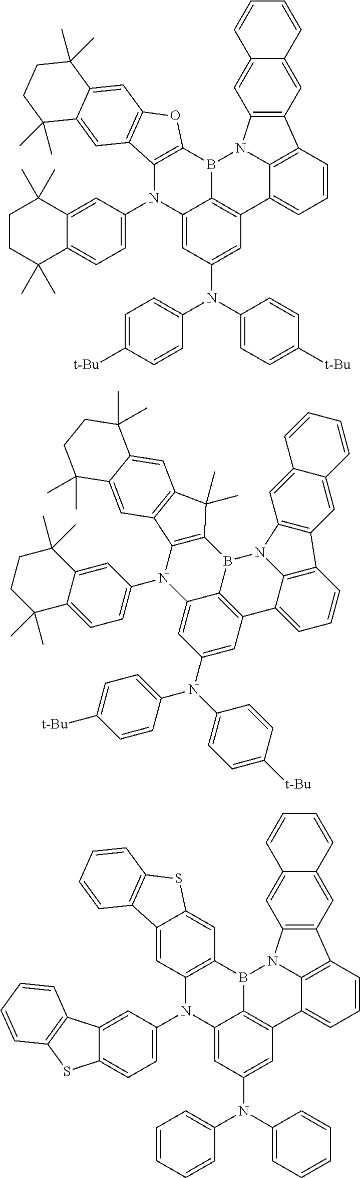 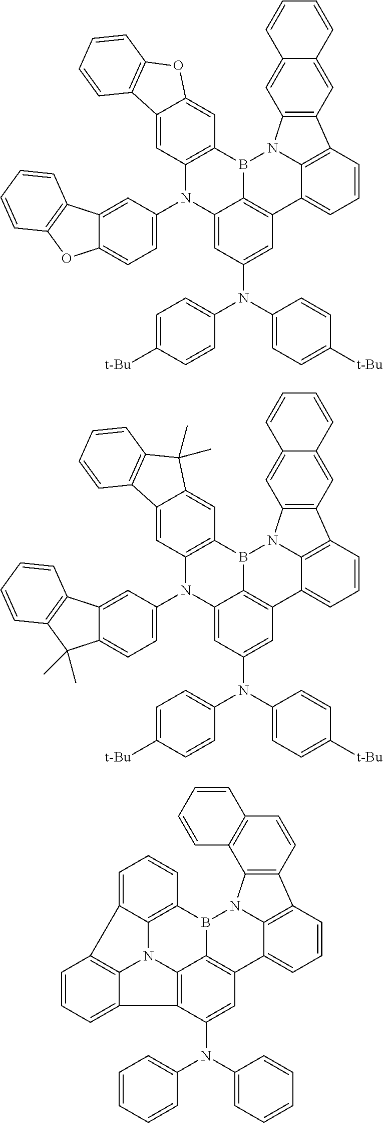 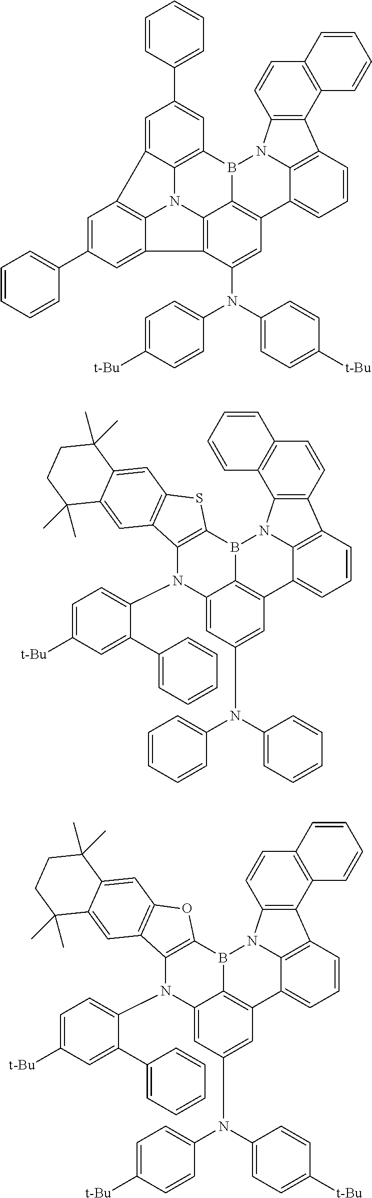 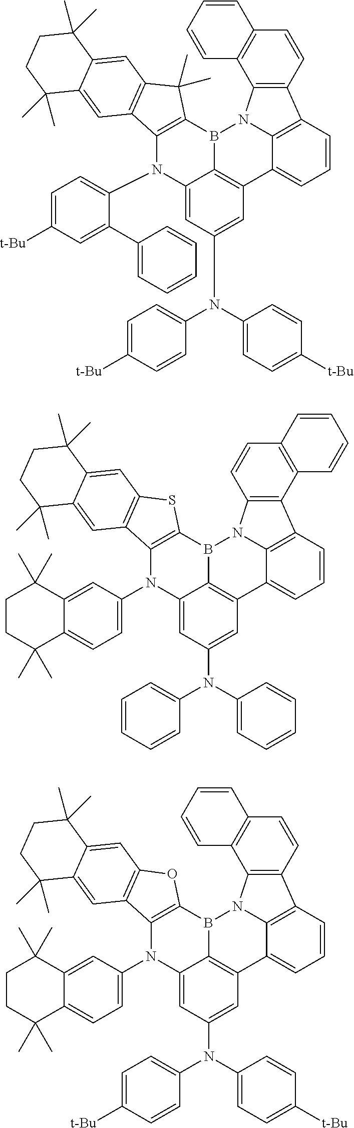 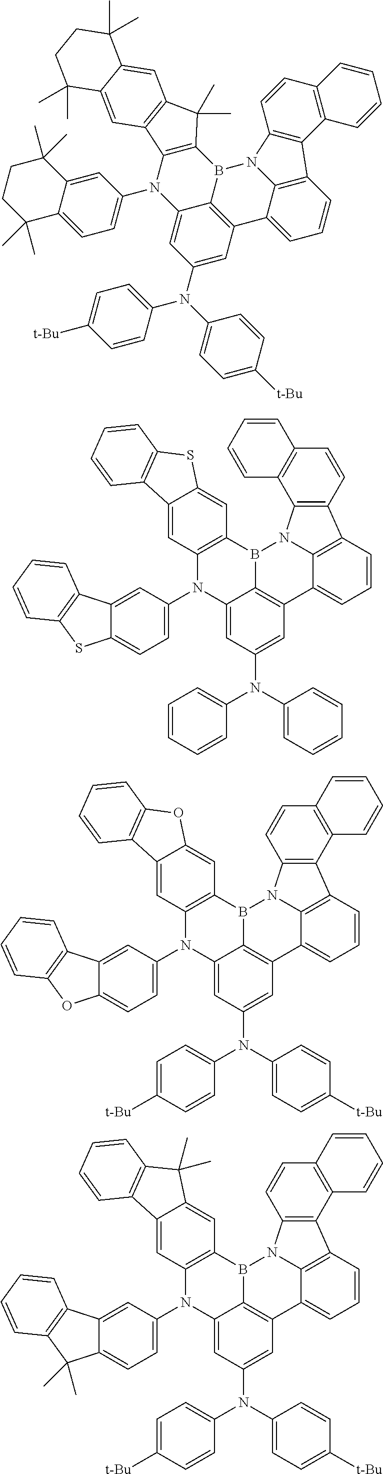 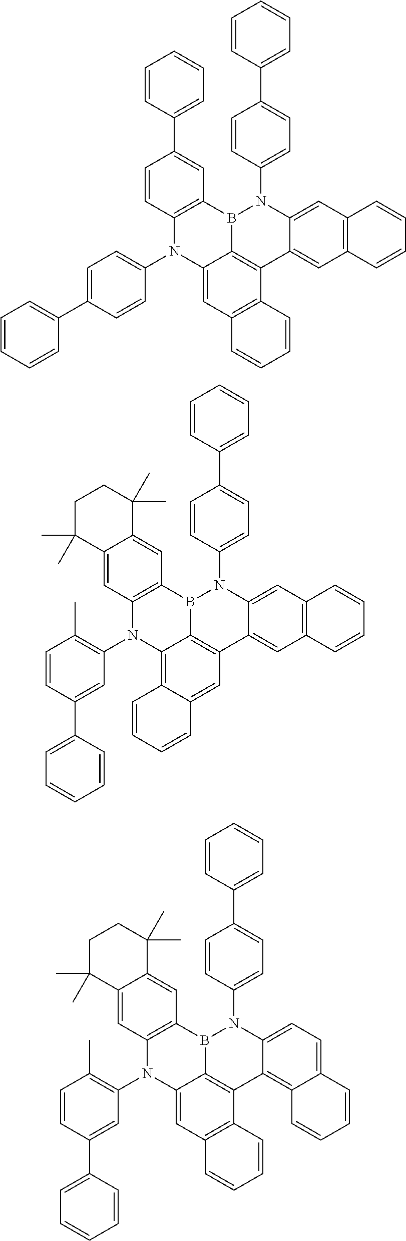 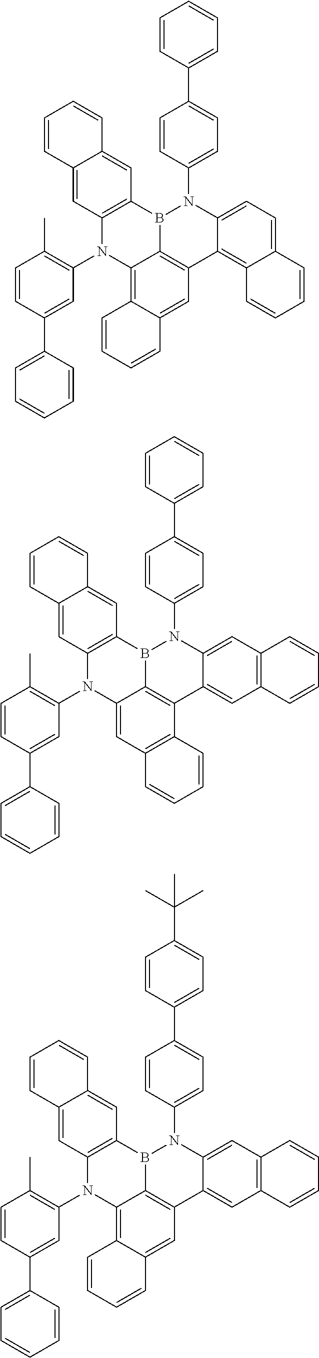 [SMILES: Cc1ccc(-c2ccccc2)cc1N1c2cc3ccccc3cc2B2c3c(cc4ccccc4c31)-c1c(ccc3ccccc13)N2c1ccc(-c2ccccc2)cc1 ; Cc1ccc(-c2ccccc2)cc1N1c2cc3ccccc3cc2B2c3c1cc1ccccc1c3-c1cc3ccccc3cc1N2c1ccc(-c2ccccc2)cc1 ; Cc1ccc(-c2ccccc2)cc1N1c2cc3ccccc3cc2B2c3c(cc4ccccc4c31)-c1cc3ccccc3cc1N2c1ccc(-c2ccc(C(C)(C)C)cc2)cc1] 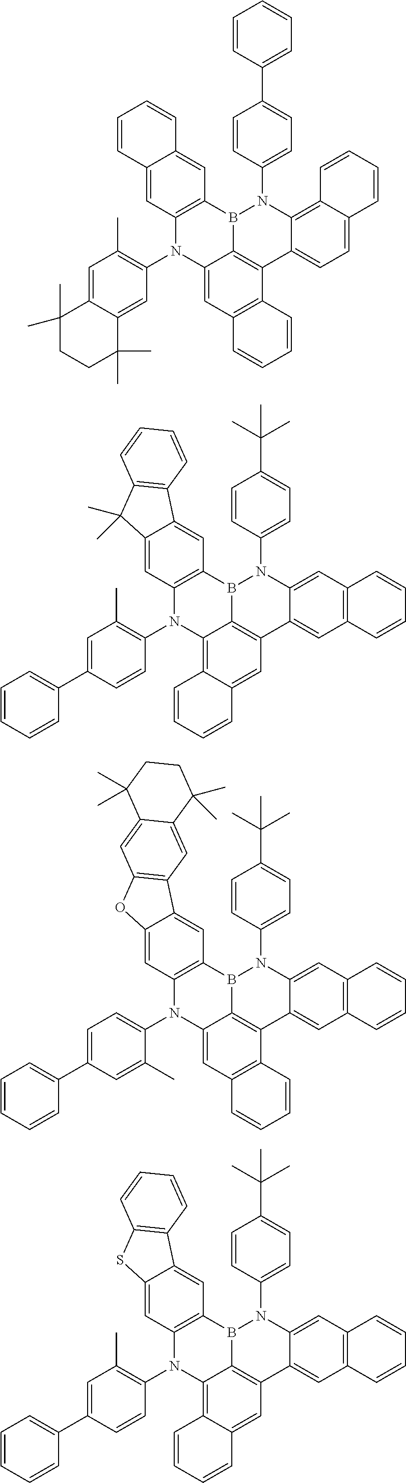 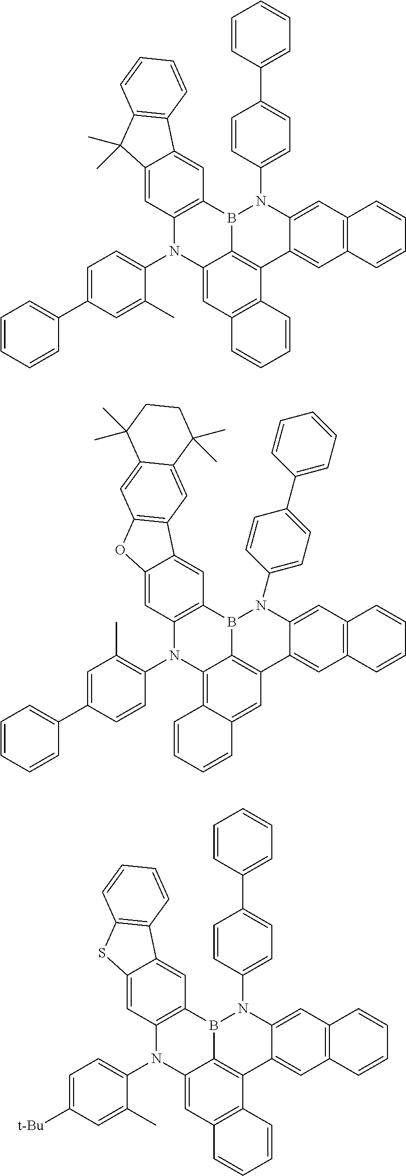 [SMILES: Cc1cc(-c2ccccc2)ccc1N1c2cc3c(cc2B2c4c1cc1ccccc1c4-c1cc4ccccc4cc1N2c1ccc(-c2ccccc2)cc1)-c1ccccc1C3(C)C ; Cc1cc(-c2ccccc2)ccc1N1c2cc3oc4cc5c(cc4c3cc2B2c3c(cc4ccccc4c31)-c1cc3ccccc3cc1N2c1ccc(-c2ccccc2)cc1)C(C)(C)CCC5(C)C ; Cc1cc(C(C)(C)C)ccc1N1c2cc3sc4ccccc4c3cc2B2c3c1cc1ccccc1c3-c1cc3ccccc3cc1N2c1ccc(-c2ccccc2)cc1] 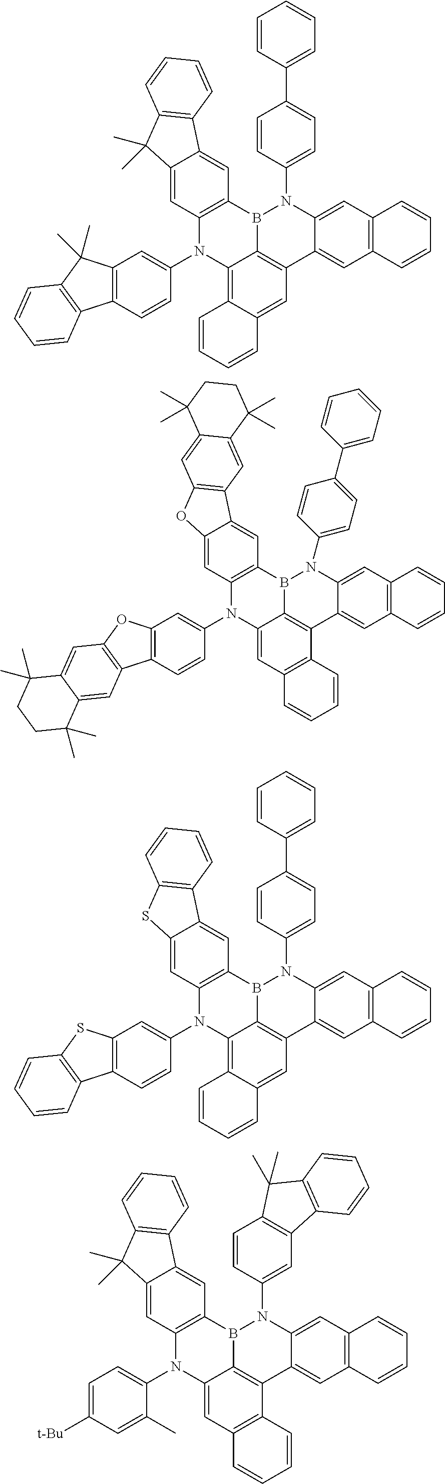 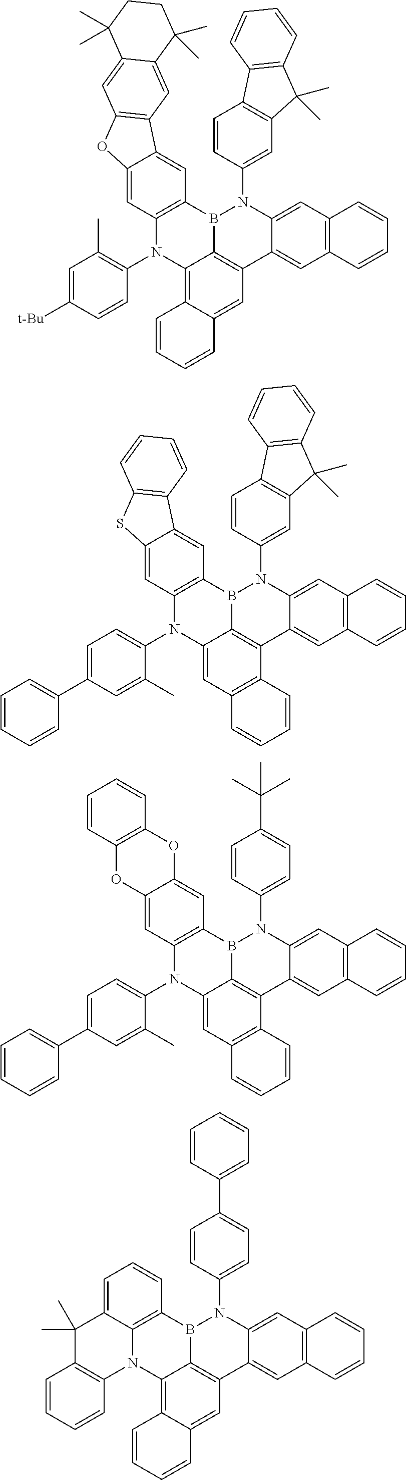 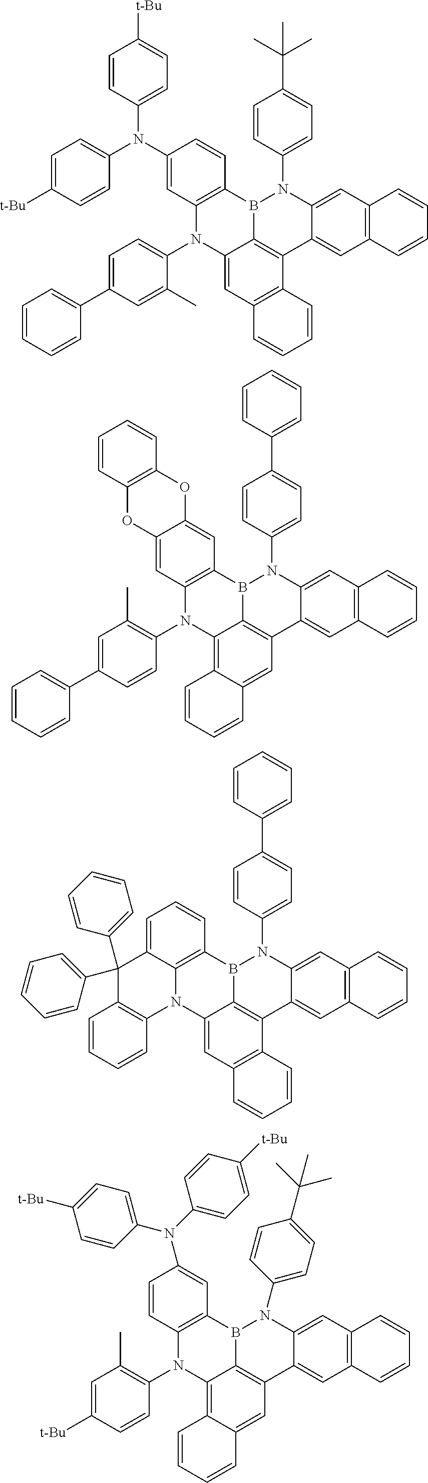 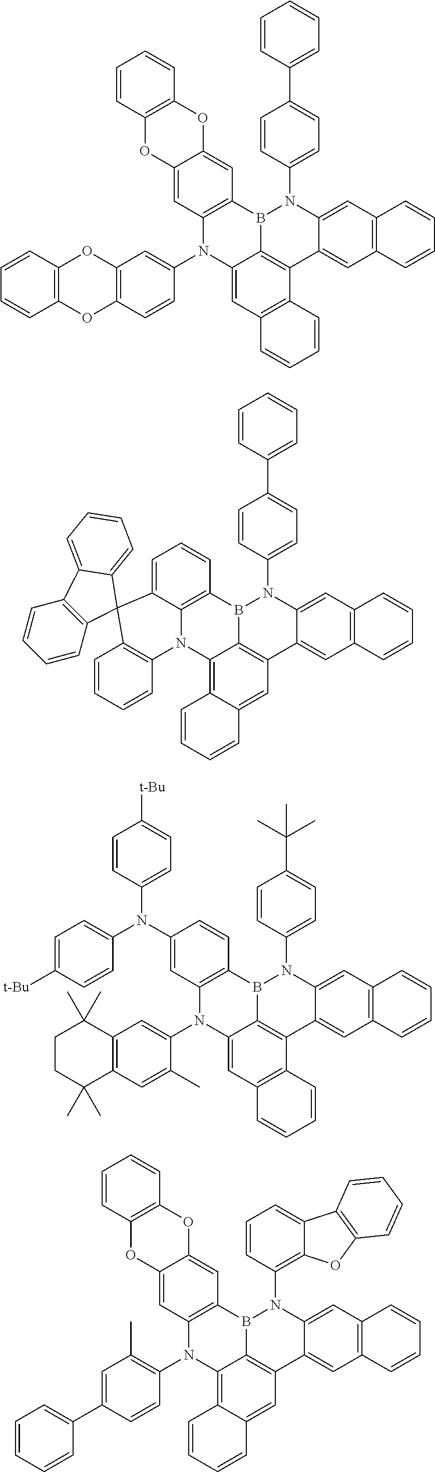 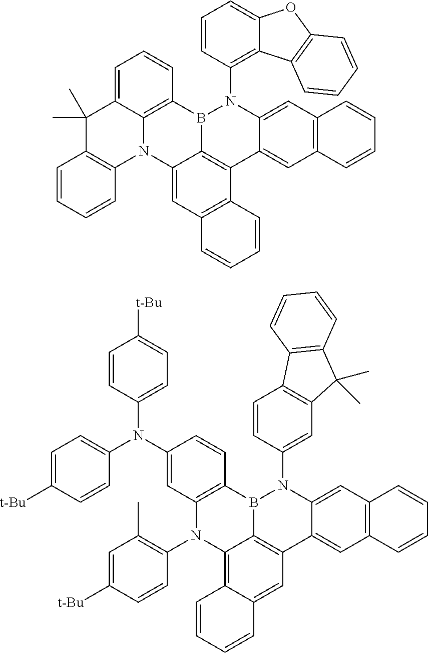 [SMILES: CC1(C)c2ccccc2N2c3cc4ccccc4c4c3B(c3cccc1c32)N(c1cccc2oc3ccccc3c12)c1cc2ccccc2cc1-4 ; Cc1cc(C(C)(C)C)ccc1N1c2cc(N(c3ccc(C(C)(C)C)cc3)c3ccc(C(C)(C)C)cc3)ccc2B2c3c(cc4ccccc4c31)-c1cc3ccccc3cc1N2c1ccc2c(c1)C(C)(C)c1ccccc1-2] 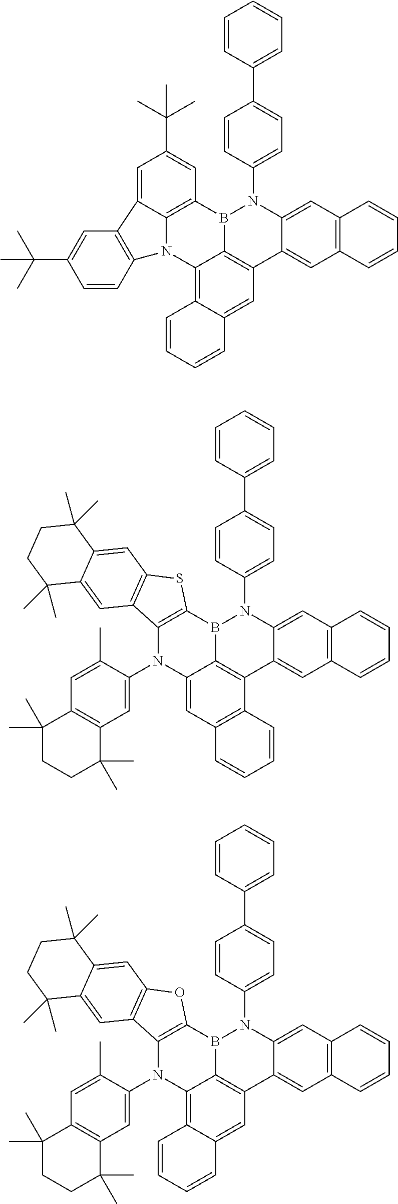 [SMILES: CC(C)(C)c1ccc2c(c1)c1cc(C(C)(C)C)cc3c1n2-c1c2c(cc4ccccc14)-c1cc4ccccc4cc1N(c1ccc(-c4ccccc4)cc1)B23 ; Cc1cc2c(cc1N1c3cc4ccccc4c4c3B(c3sc5cc6c(cc5c31)C(C)(C)CCC6(C)C)N(c1ccc(-c3ccccc3)cc1)c1cc3ccccc3cc1-4)C(C)(C)CCC2(C)C ; Cc1cc2c(cc1N1c3c4c(cc5ccccc35)-c3cc5ccccc5cc3N(c3ccc(-c5ccccc5)cc3)B4c3oc4cc5c(cc4c31)C(C)(C)CCC5(C)C)C(C)(C)CCC2(C)C] 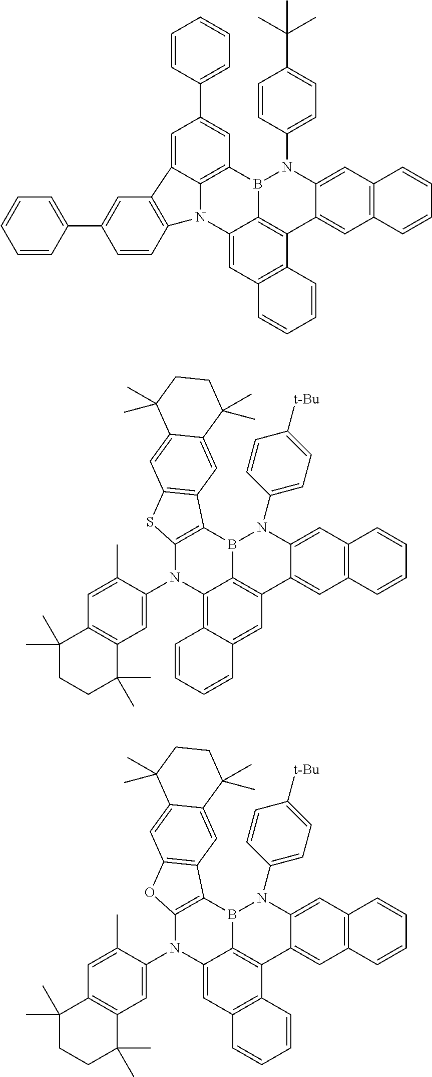 [SMILES: CC(C)(C)c1ccc(N2B3c4c(cc5ccccc5c4-c4cc5ccccc5cc42)-n2c4ccc(-c5ccccc5)cc4c4cc(-c5ccccc5)cc3c42)cc1 ; Cc1cc2c(cc1N1c3sc4cc5c(cc4c3B3c4c(cc6ccccc6c41)-c1cc4ccccc4cc1N3c1ccc(C(C)(C)C)cc1)C(C)(C)CCC5(C)C)C(C)(C)CCC2(C)C ; Cc1cc2c(cc1N1c3cc4ccccc4c4c3B(c3c1oc1cc5c(cc31)C(C)(C)CCC5(C)C)N(c1ccc(C(C)(C)C)cc1)c1cc3ccccc3cc1-4)C(C)(C)CCC2(C)C] 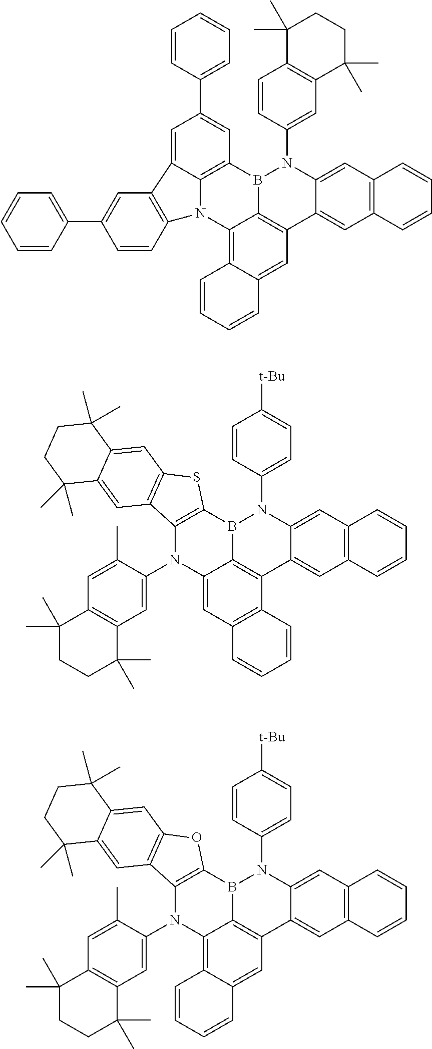 [SMILES: CC1(C)CCC(C)(C)c2cc(N3B4c5c(cc6ccccc6c5-n5c6ccc(-c7ccccc7)cc6c6cc(-c7ccccc7)cc4c65)-c4cc5ccccc5cc43)ccc21 ; Cc1cc2c(cc1N1c3cc4ccccc4c4c3B(c3sc5cc6c(cc5c31)C(C)(C)CCC6(C)C)N(c1ccc(C(C)(C)C)cc1)c1cc3ccccc3cc1-4)C(C)(C)CCC2(C)C ; Cc1cc2c(cc1N1c3c4c(cc5ccccc35)-c3cc5ccccc5cc3N(c3ccc(C(C)(C)C)cc3)B4c3oc4cc5c(cc4c31)C(C)(C)CCC5(C)C)C(C)(C)CCC2(C)C] 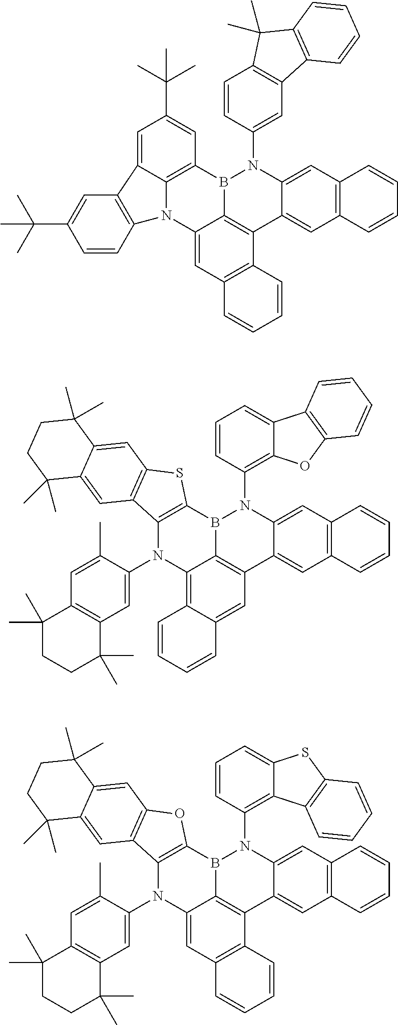 [SMILES: CC(C)(C)c1ccc2c(c1)c1cc(C(C)(C)C)cc3c1n2-c1cc2ccccc2c2c1B3N(c1ccc3c(c1)-c1ccccc1C3(C)C)c1cc3ccccc3cc1-2 ; Cc1cc2c(cc1N1c3c4c(cc5ccccc35)-c3cc5ccccc5cc3N(c3cccc5c3oc3ccccc35)B4c3sc4cc5c(cc4c31)C(C)(C)CCC5(C)C)C(C)(C)CCC2(C)C ; Cc1cc2c(cc1N1c3cc4ccccc4c4c3B(c3oc5cc6c(cc5c31)C(C)(C)CCC6(C)C)N(c1cccc3sc5ccccc5c13)c1cc3ccccc3cc1-4)C(C)(C)CCC2(C)C] 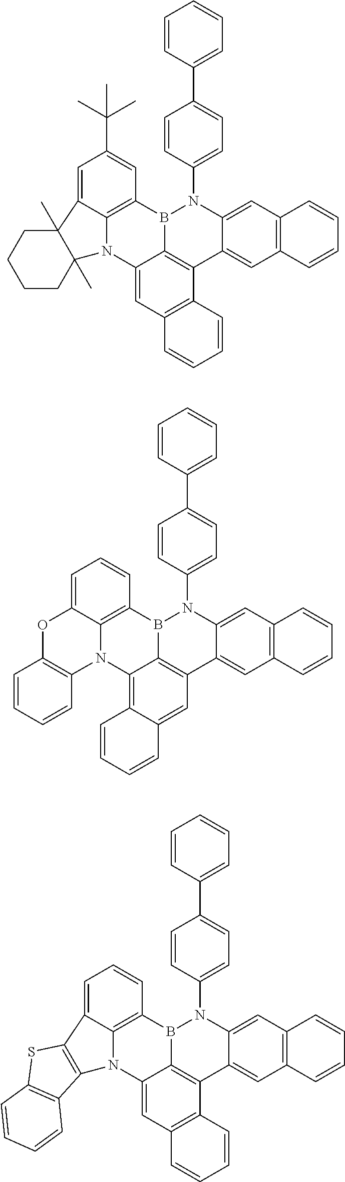 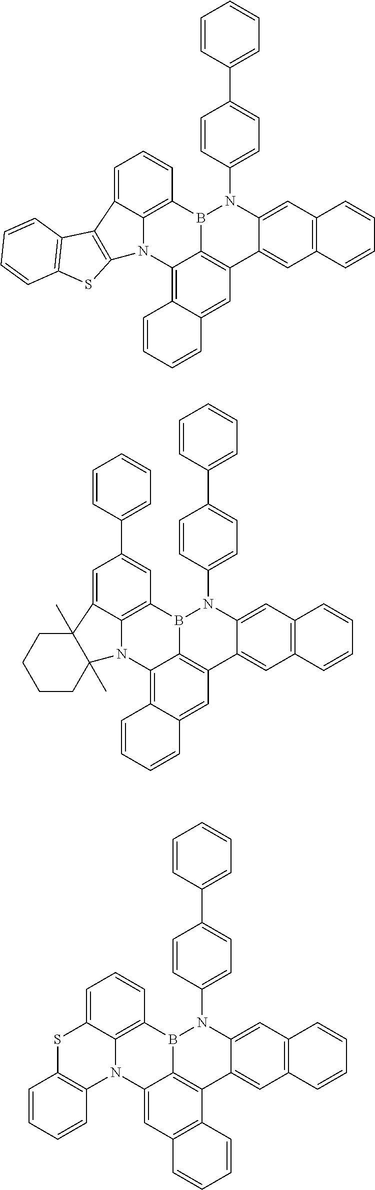 [SMILES: c1ccc(-c2ccc(N3B4c5c(cc6ccccc6c5-n5c6sc7ccccc7c6c6cccc4c65)-c4cc5ccccc5cc43)cc2)cc1 ; CC12CCCCC1(C)N1c3c(cc(-c4ccccc4)cc32)B2c3c(cc4ccccc4c31)-c1cc3ccccc3cc1N2c1ccc(-c2ccccc2)cc1 ; c1ccc(-c2ccc(N3B4c5cccc6c5N(c5ccccc5S6)c5cc6ccccc6c(c54)-c4cc5ccccc5cc43)cc2)cc1] 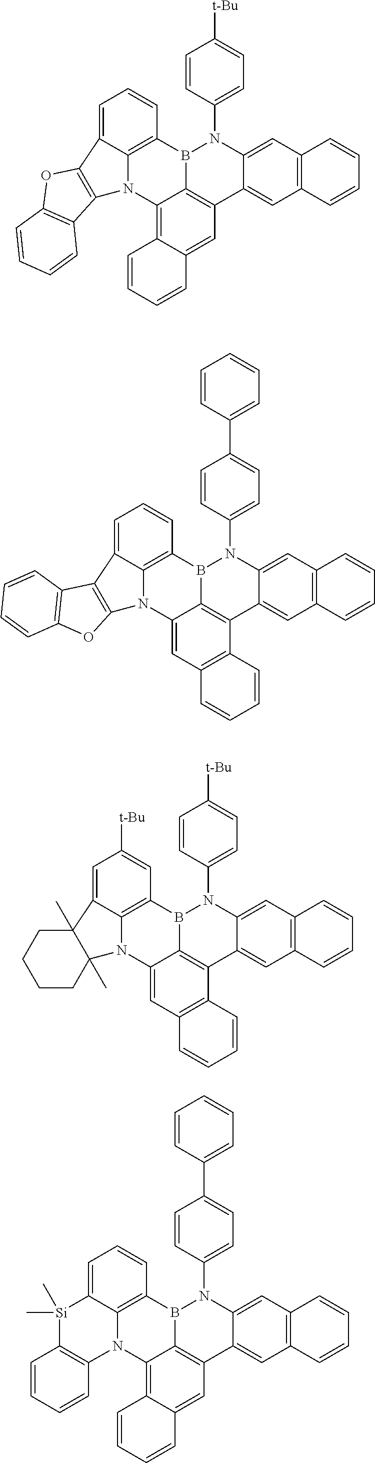 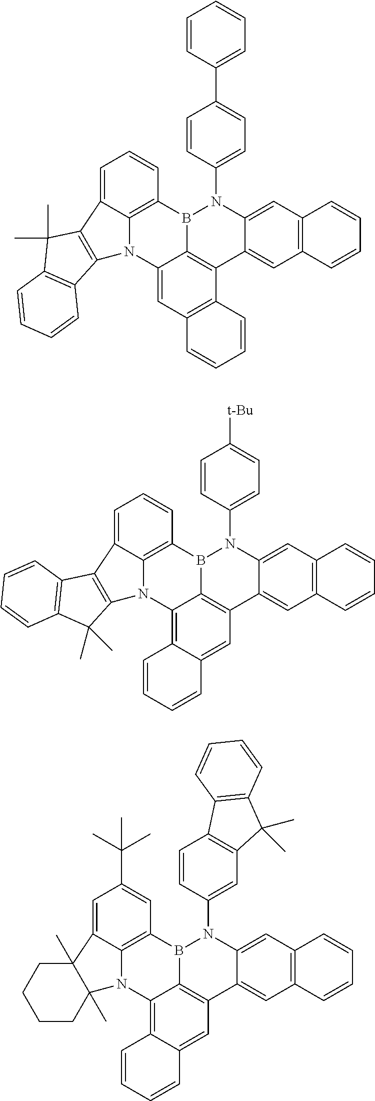 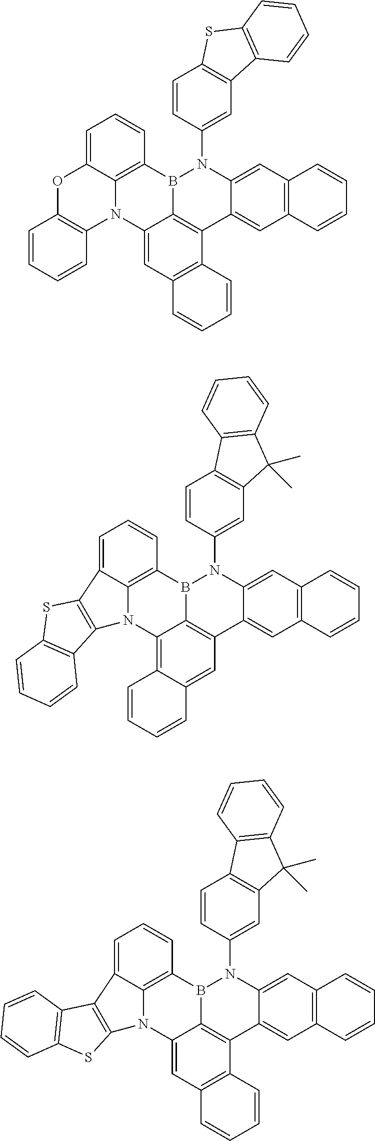 [SMILES: c1ccc2c(c1)Oc1cccc3c1N2c1cc2ccccc2c2c1B3N(c1ccc3sc4ccccc4c3c1)c1cc3ccccc3cc1-2 ; CC1(C)c2ccccc2-c2ccc(N3B4c5c(cc6ccccc6c5-n5c6c4cccc6c4sc6ccccc6c45)-c4cc5ccccc5cc43)cc21 ; CC1(C)c2ccccc2-c2ccc(N3B4c5c(cc6ccccc6c5-c5cc6ccccc6cc53)-n3c5sc6ccccc6c5c5cccc4c53)cc21] 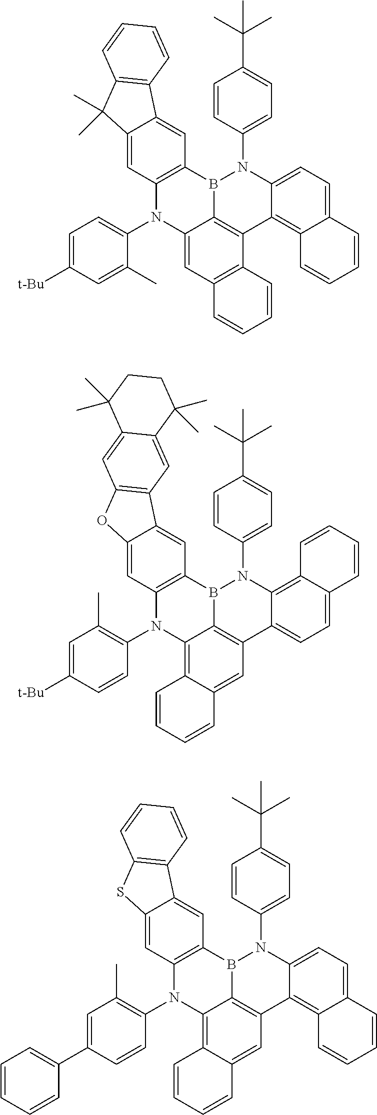 [SMILES: Cc1cc(C(C)(C)C)ccc1N1c2cc3c(cc2B2c4c1cc1ccccc1c4-c1c(ccc4ccccc14)N2c1ccc(C(C)(C)C)cc1)-c1ccccc1C3(C)C ; Cc1cc(C(C)(C)C)ccc1N1c2cc3oc4cc5c(cc4c3cc2B2c3c(cc4ccccc4c31)-c1ccc3ccccc3c1N2c1ccc(C(C)(C)C)cc1)C(C)(C)CCC5(C)C ; Cc1cc(-c2ccccc2)ccc1N1c2cc3sc4ccccc4c3cc2B2c3c(cc4ccccc4c31)-c1c(ccc3ccccc13)N2c1ccc(C(C)(C)C)cc1] 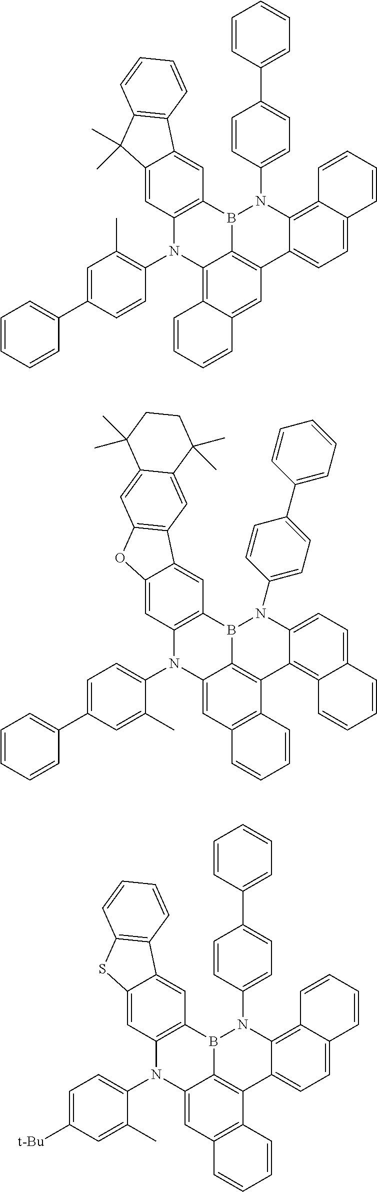 [SMILES: Cc1cc(-c2ccccc2)ccc1N1c2cc3c(cc2B2c4c(cc5ccccc5c41)-c1ccc4ccccc4c1N2c1ccc(-c2ccccc2)cc1)-c1ccccc1C3(C)C ; Cc1cc(-c2ccccc2)ccc1N1c2cc3oc4cc5c(cc4c3cc2B2c3c1cc1ccccc1c3-c1c(ccc3ccccc13)N2c1ccc(-c2ccccc2)cc1)C(C)(C)CCC5(C)C ; Cc1cc(C(C)(C)C)ccc1N1c2cc3sc4ccccc4c3cc2B2c3c1cc1ccccc1c3-c1ccc3ccccc3c1N2c1ccc(-c2ccccc2)cc1] 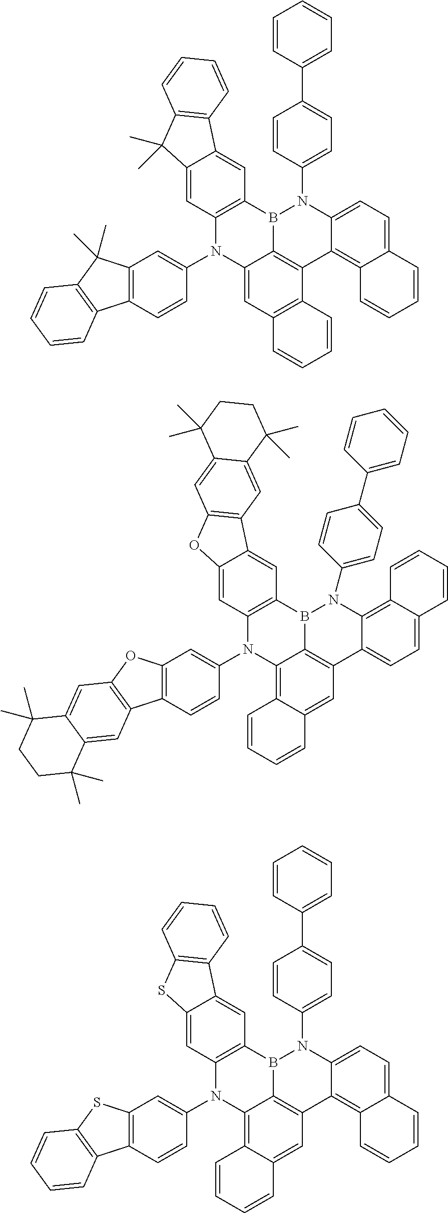 [SMILES: CC1(C)c2ccccc2-c2ccc(N3c4cc5c(cc4B4c6c3cc3ccccc3c6-c3c(ccc6ccccc36)N4c3ccc(-c4ccccc4)cc3)-c3ccccc3C5(C)C)cc21 ; CC1(C)CCC(C)(C)c2cc3c(cc21)oc1cc(N2c4cc5oc6cc7c(cc6c5cc4B4c5c(cc6ccccc6c52)-c2ccc5ccccc5c2N4c2ccc(-c4ccccc4)cc2)C(C)(C)CCC7(C)C)ccc13 ; c1ccc(-c2ccc(N3B4c5cc6c(cc5N(c5ccc7c(c5)sc5ccccc57)c5c4c(cc4ccccc54)-c4c3ccc3ccccc43)sc3ccccc36)cc2)cc1] 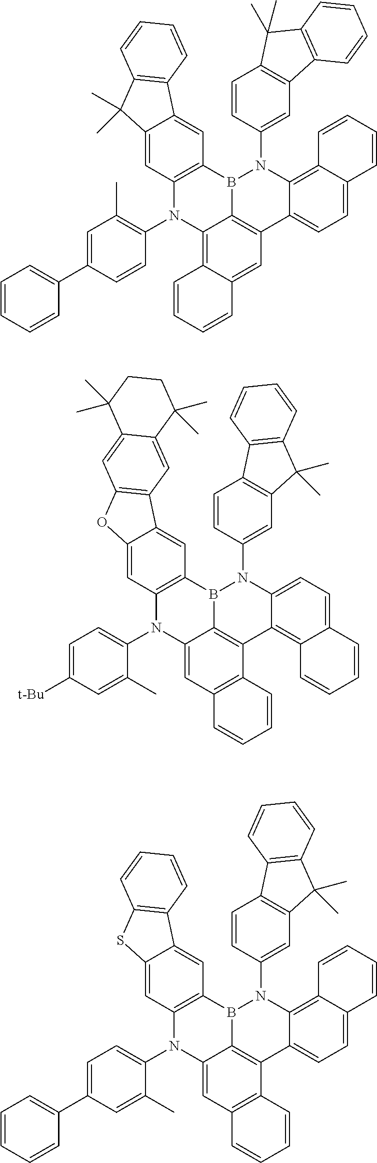 [SMILES: Cc1cc(-c2ccccc2)ccc1N1c2cc3c(cc2B2c4c(cc5ccccc5c41)-c1ccc4ccccc4c1N2c1ccc2c(c1)-c1ccccc1C2(C)C)-c1ccccc1C3(C)C ; Cc1cc(C(C)(C)C)ccc1N1c2cc3oc4cc5c(cc4c3cc2B2c3c1cc1ccccc1c3-c1c(ccc3ccccc13)N2c1ccc2c(c1)C(C)(C)c1ccccc1-2)C(C)(C)CCC5(C)C ; Cc1cc(-c2ccccc2)ccc1N1c2cc3sc4ccccc4c3cc2B2c3c1cc1ccccc1c3-c1ccc3ccccc3c1N2c1ccc2c(c1)C(C)(C)c1ccccc1-2] 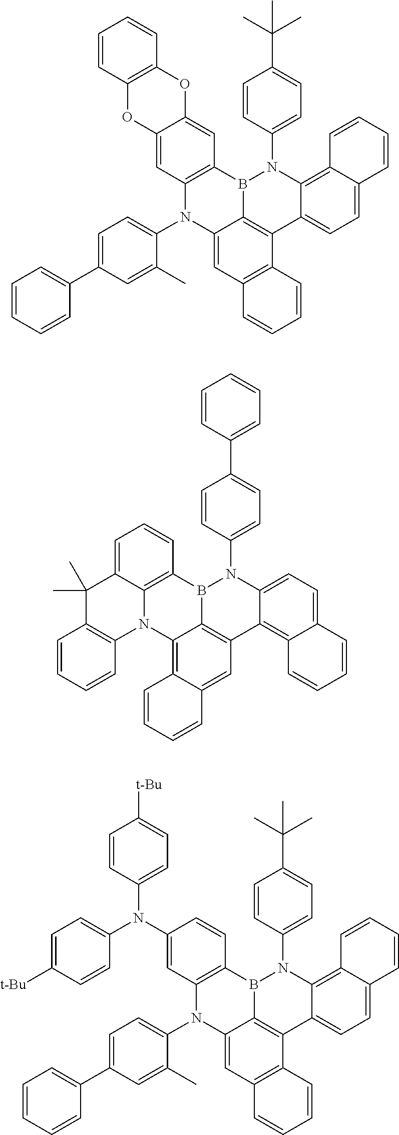 [SMILES: Cc1cc(-c2ccccc2)ccc1N1c2cc3c(cc2B2c4c1cc1ccccc1c4-c1ccc4ccccc4c1N2c1ccc(C(C)(C)C)cc1)Oc1ccccc1O3 ; CC1(C)c2ccccc2N2c3c(cccc31)B1c3c(cc4ccccc4c32)-c2c(ccc3ccccc23)N1c1ccc(-c2ccccc2)cc1 ; Cc1cc(-c2ccccc2)ccc1N1c2cc(N(c3ccc(C(C)(C)C)cc3)c3ccc(C(C)(C)C)cc3)ccc2B2c3c1cc1ccccc1c3-c1ccc3ccccc3c1N2c1ccc(C(C)(C)C)cc1] 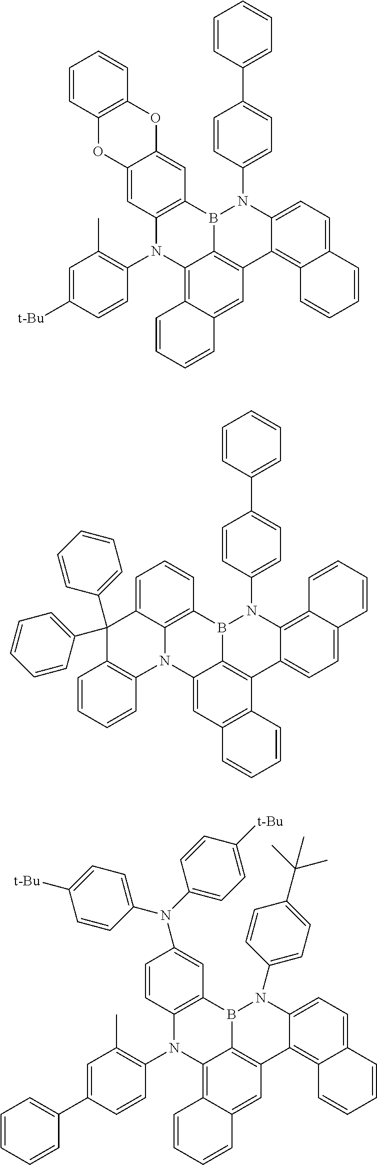 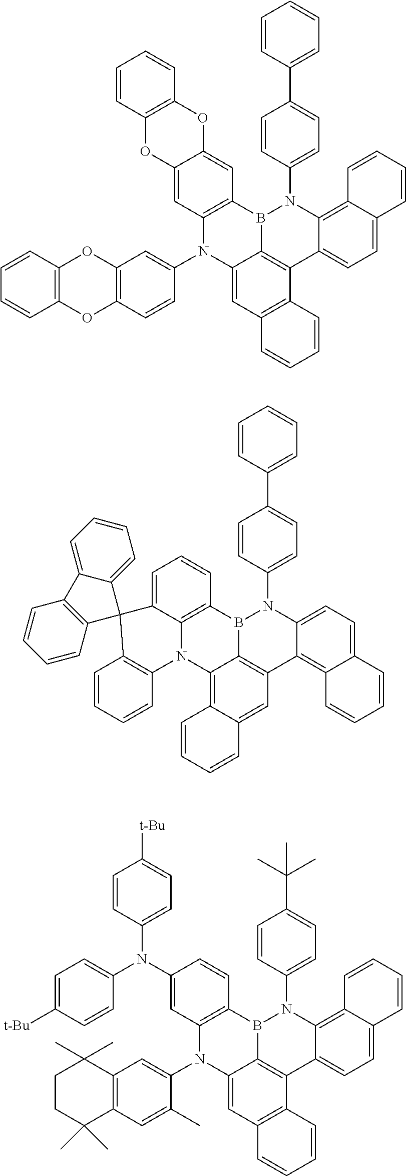 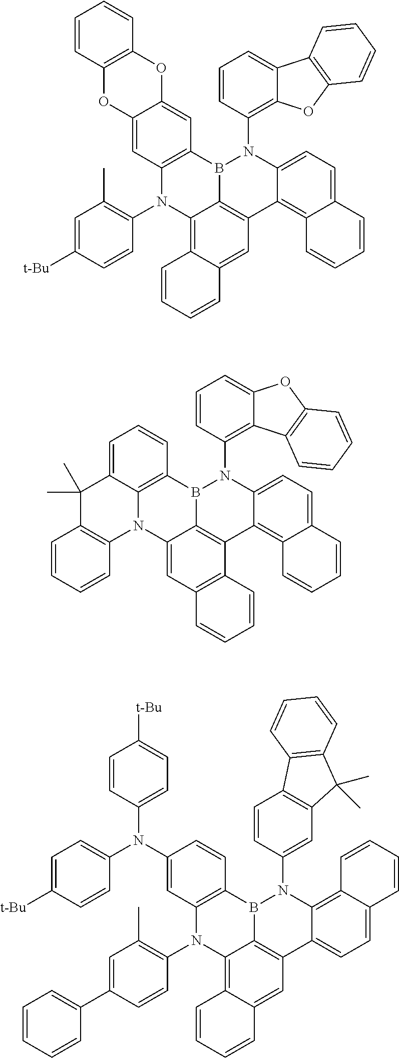 [SMILES: Cc1cc(C(C)(C)C)ccc1N1c2cc3c(cc2B2c4c(cc5ccccc5c41)-c1c(ccc4ccccc14)N2c1cccc2c1oc1ccccc12)Oc1ccccc1O3 ; CC1(C)c2ccccc2N2c3cc4ccccc4c4c3B(c3cccc1c32)N(c1cccc2oc3ccccc3c12)c1ccc2ccccc2c1-4 ; Cc1cc(-c2ccccc2)ccc1N1c2cc(N(c3ccc(C(C)(C)C)cc3)c3ccc(C(C)(C)C)cc3)ccc2B2c3c(cc4ccccc4c31)-c1ccc3ccccc3c1N2c1ccc2c(c1)C(C)(C)c1ccccc1-2] 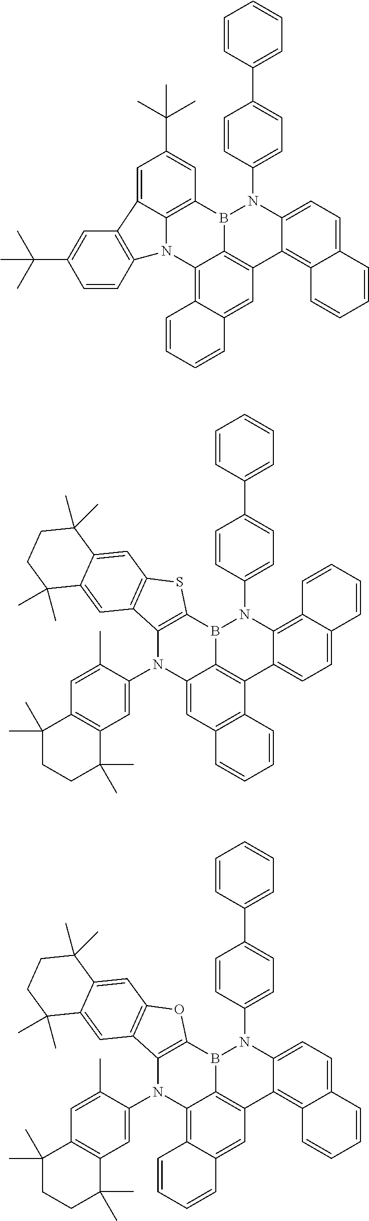 [SMILES: CC(C)(C)c1ccc2c(c1)c1cc(C(C)(C)C)cc3c1n2-c1c2c(cc4ccccc14)-c1c(ccc4ccccc14)N(c1ccc(-c4ccccc4)cc1)B23 ; Cc1cc2c(cc1N1c3cc4ccccc4c4c3B(c3sc5cc6c(cc5c31)C(C)(C)CCC6(C)C)N(c1ccc(-c3ccccc3)cc1)c1c-4ccc3ccccc13)C(C)(C)CCC2(C)C ; Cc1cc2c(cc1N1c3c4c(cc5ccccc35)-c3c(ccc5ccccc35)N(c3ccc(-c5ccccc5)cc3)B4c3oc4cc5c(cc4c31)C(C)(C)CCC5(C)C)C(C)(C)CCC2(C)C] 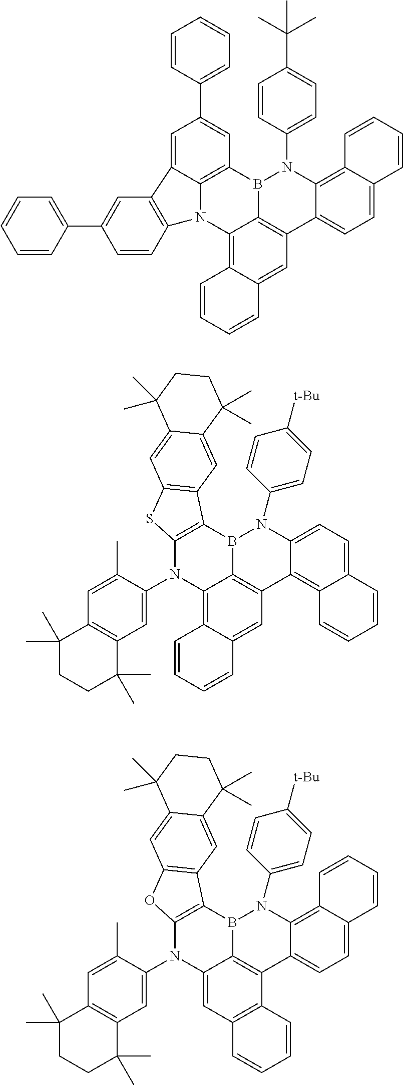 [SMILES: CC(C)(C)c1ccc(N2B3c4c(cc5ccccc5c4-n4c5ccc(-c6ccccc6)cc5c5cc(-c6ccccc6)cc3c54)-c3ccc4ccccc4c32)cc1 ; Cc1cc2c(cc1N1c3sc4cc5c(cc4c3B3c4c(cc6ccccc6c41)-c1c(ccc4ccccc14)N3c1ccc(C(C)(C)C)cc1)C(C)(C)CCC5(C)C)C(C)(C)CCC2(C)C ; Cc1cc2c(cc1N1c3cc4ccccc4c4c3B(c3c1oc1cc5c(cc31)C(C)(C)CCC5(C)C)N(c1ccc(C(C)(C)C)cc1)c1c-4ccc3ccccc13)C(C)(C)CCC2(C)C] 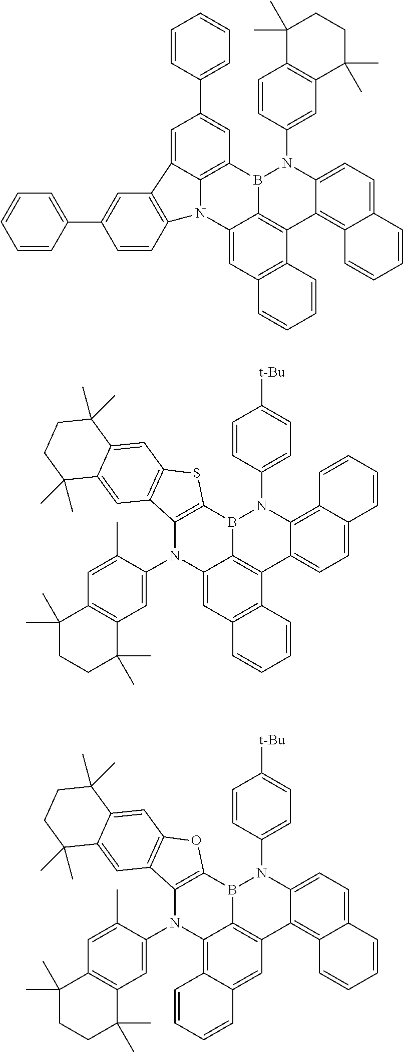 [SMILES: CC1(C)CCC(C)(C)c2cc(N3B4c5c(cc6ccccc6c5-c5c3ccc3ccccc53)-n3c5ccc(-c6ccccc6)cc5c5cc(-c6ccccc6)cc4c53)ccc21 ; Cc1cc2c(cc1N1c3cc4ccccc4c4c3B(c3sc5cc6c(cc5c31)C(C)(C)CCC6(C)C)N(c1ccc(C(C)(C)C)cc1)c1c-4ccc3ccccc13)C(C)(C)CCC2(C)C ; Cc1cc2c(cc1N1c3c4c(cc5ccccc35)-c3c(ccc5ccccc35)N(c3ccc(C(C)(C)C)cc3)B4c3oc4cc5c(cc4c31)C(C)(C)CCC5(C)C)C(C)(C)CCC2(C)C] 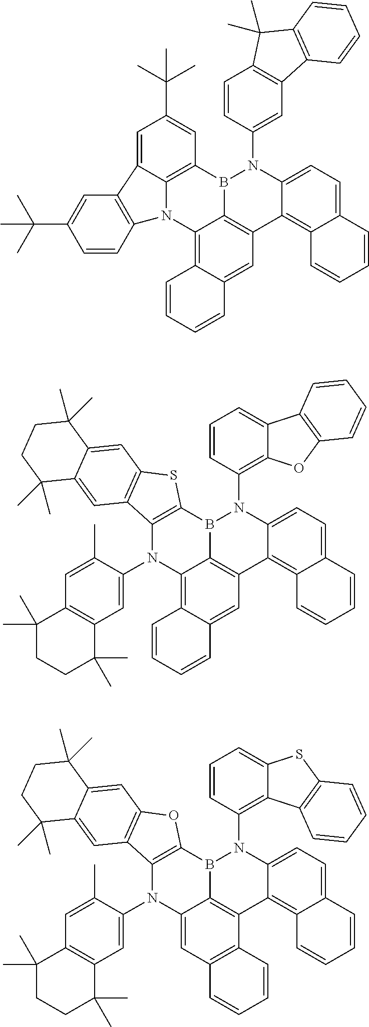 [SMILES: CC(C)(C)c1ccc2c(c1)c1cc(C(C)(C)C)cc3c1n2-c1c2c(cc4ccccc14)-c1c(ccc4ccccc14)N(c1ccc4c(c1)-c1ccccc1C4(C)C)B23 ; Cc1cc2c(cc1N1c3c4c(cc5ccccc35)-c3c(ccc5ccccc35)N(c3cccc5c3oc3ccccc35)B4c3sc4cc5c(cc4c31)C(C)(C)CCC5(C)C)C(C)(C)CCC2(C)C ; Cc1cc2c(cc1N1c3cc4ccccc4c4c3B(c3oc5cc6c(cc5c31)C(C)(C)CCC6(C)C)N(c1cccc3sc5ccccc5c13)c1ccc3ccccc3c1-4)C(C)(C)CCC2(C)C] 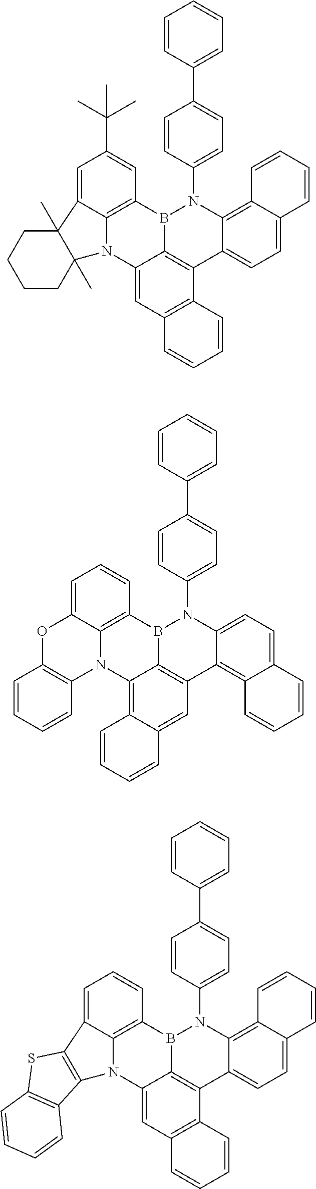 [SMILES: CC(C)(C)c1cc2c3c(c1)C1(C)CCCCC1(C)N3c1cc3ccccc3c3c1B2N(c1ccc(-c2ccccc2)cc1)c1c-3ccc2ccccc12 ; c1ccc(-c2ccc(N3B4c5cccc6c5N(c5ccccc5O6)c5c4c(cc4ccccc54)-c4c3ccc3ccccc43)cc2)cc1 ; c1ccc(-c2ccc(N3B4c5c(cc6ccccc6c5-c5ccc6ccccc6c53)-n3c5c4cccc5c4sc5ccccc5c43)cc2)cc1] 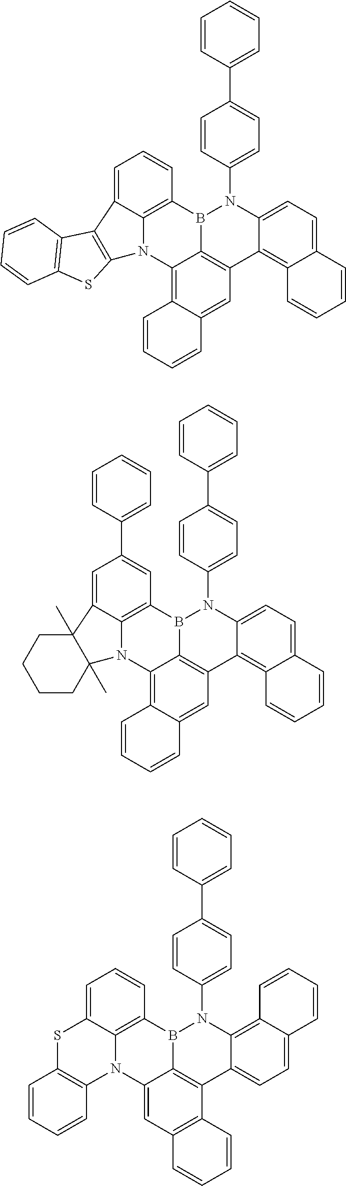 [SMILES: c1ccc(-c2ccc(N3B4c5c(cc6ccccc6c5-n5c6sc7ccccc7c6c6cccc4c65)-c4c3ccc3ccccc43)cc2)cc1 ; CC12CCCCC1(C)N1c3c(cc(-c4ccccc4)cc32)B2c3c(cc4ccccc4c31)-c1c(ccc3ccccc13)N2c1ccc(-c2ccccc2)cc1 ; c1ccc(-c2ccc(N3B4c5cccc6c5N(c5ccccc5S6)c5cc6ccccc6c(c54)-c4ccc5ccccc5c43)cc2)cc1] 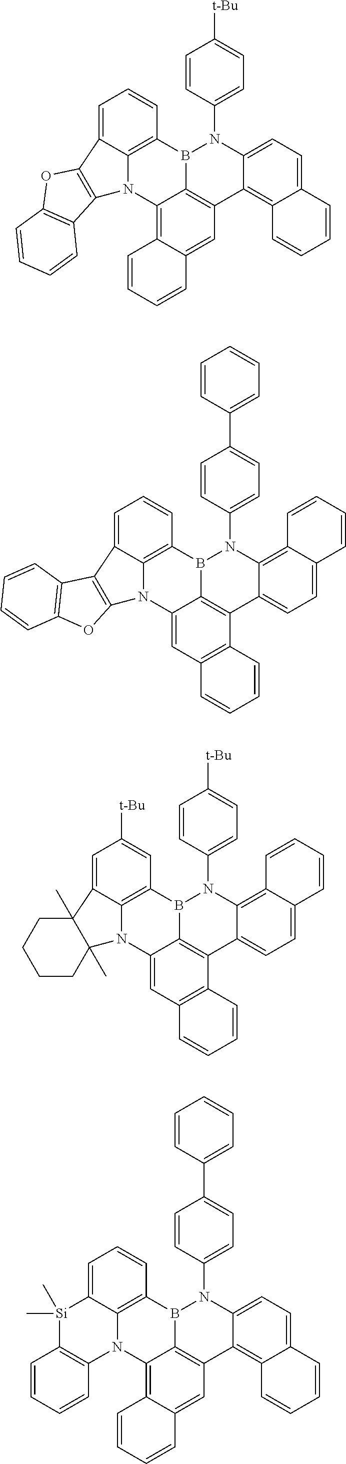 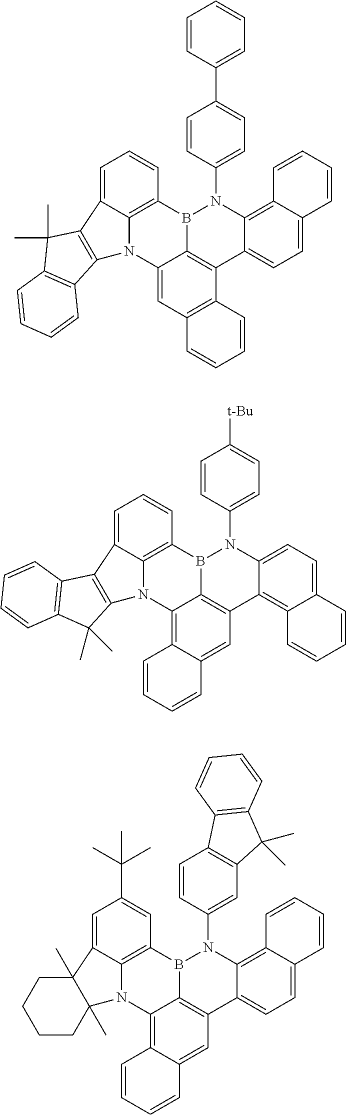 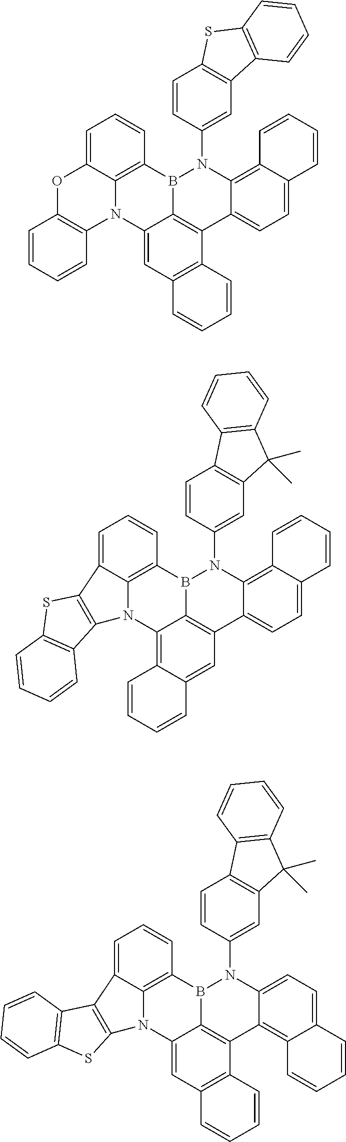 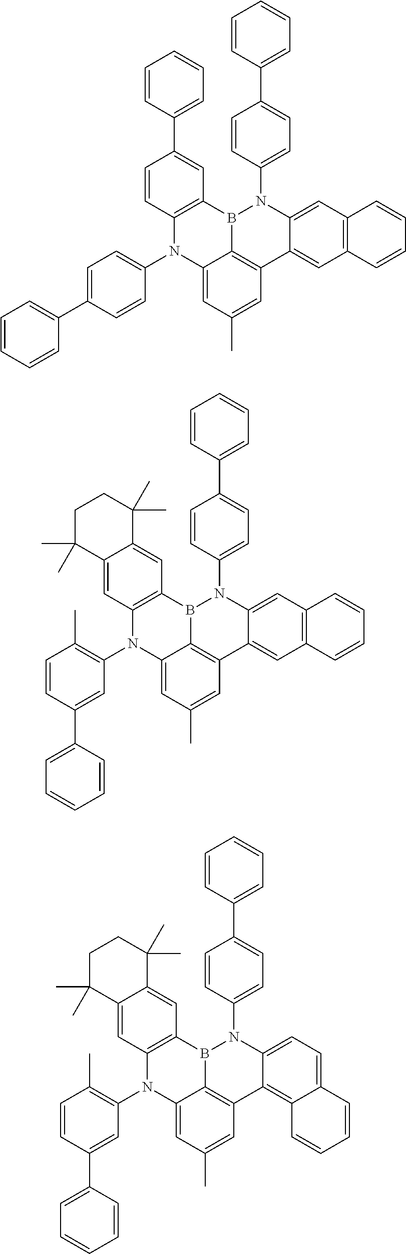 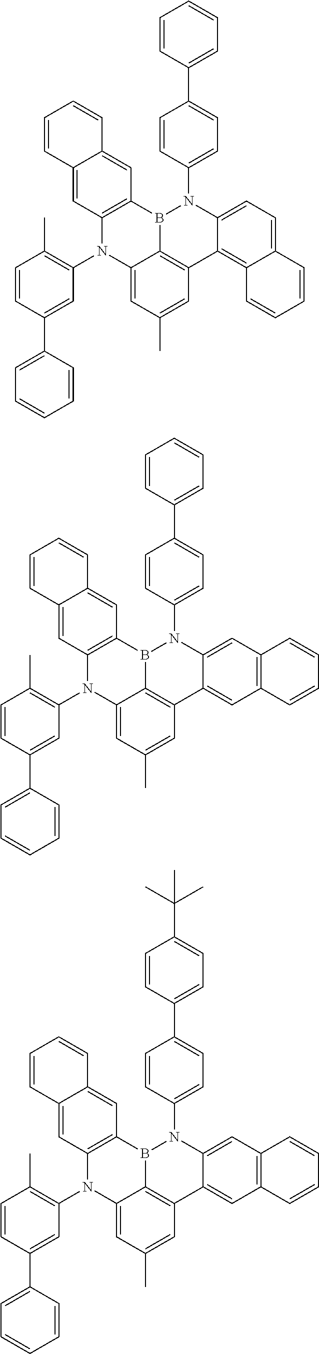 [SMILES: Cc1cc2c3c(c1)N(c1cc(-c4ccccc4)ccc1C)c1cc4ccccc4cc1B3N(c1ccc(-c3ccccc3)cc1)c1ccc3ccccc3c1-2 ; Cc1cc2c3c(c1)N(c1cc(-c4ccccc4)ccc1C)c1cc4ccccc4cc1B3N(c1ccc(-c3ccccc3)cc1)c1cc3ccccc3cc1-2 ; Cc1cc2c3c(c1)N(c1cc(-c4ccccc4)ccc1C)c1cc4ccccc4cc1B3N(c1ccc(-c3ccc(C(C)(C)C)cc3)cc1)c1cc3ccccc3cc1-2] 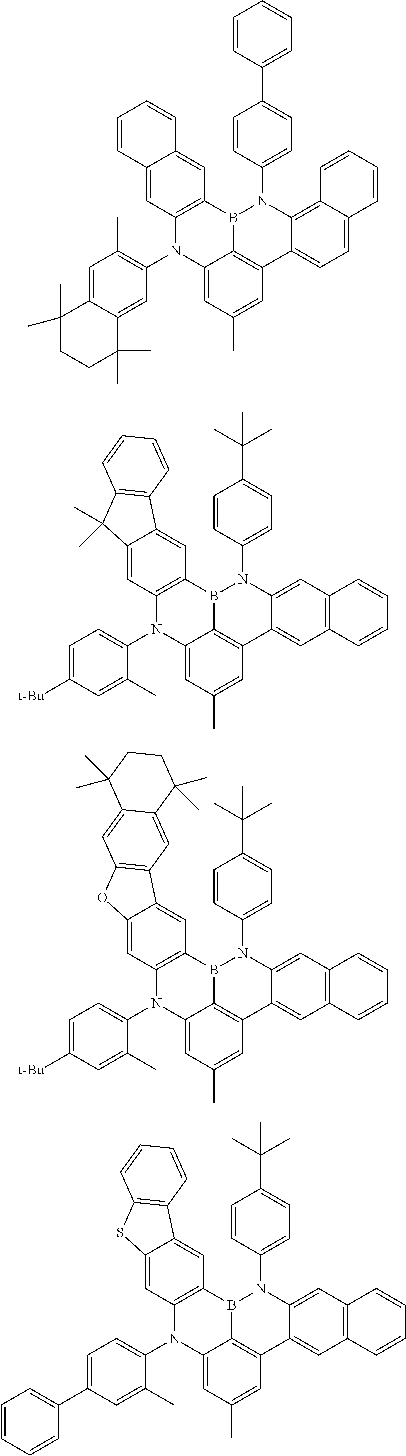 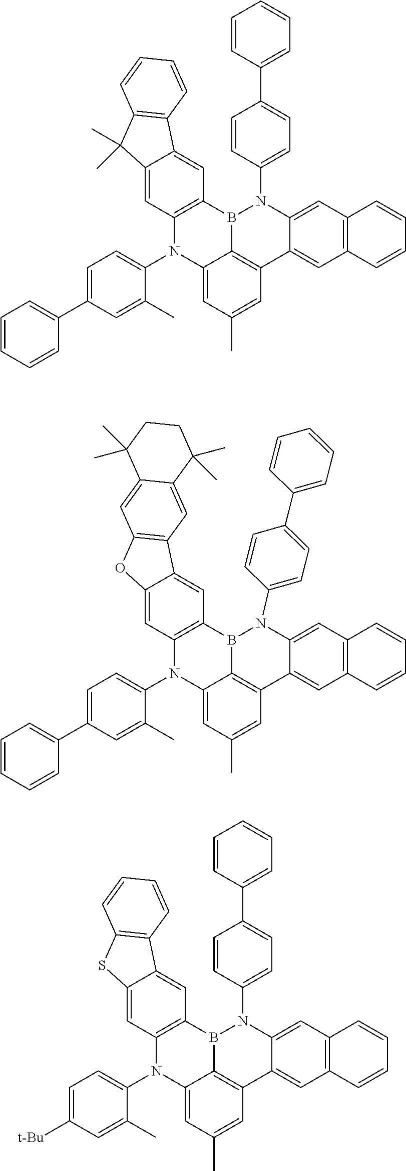 [SMILES: Cc1cc2c3c(c1)N(c1ccc(-c4ccccc4)cc1C)c1cc4c(cc1B3N(c1ccc(-c3ccccc3)cc1)c1cc3ccccc3cc1-2)-c1ccccc1C4(C)C ; Cc1cc2c3c(c1)N(c1ccc(-c4ccccc4)cc1C)c1cc4oc5cc6c(cc5c4cc1B3N(c1ccc(-c3ccccc3)cc1)c1cc3ccccc3cc1-2)C(C)(C)CCC6(C)C ; Cc1cc2c3c(c1)N(c1ccc(C(C)(C)C)cc1C)c1cc4sc5ccccc5c4cc1B3N(c1ccc(-c3ccccc3)cc1)c1cc3ccccc3cc1-2] 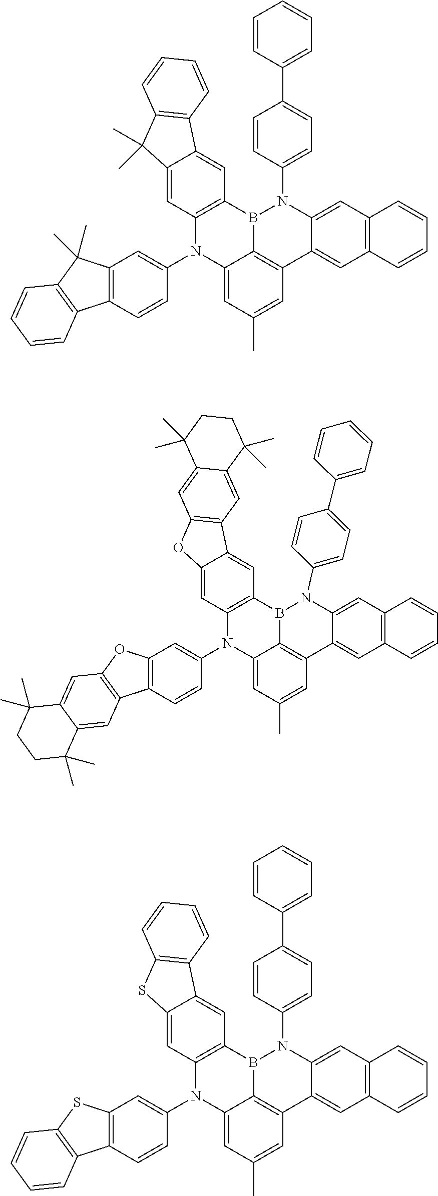 [SMILES: Cc1cc2c3c(c1)N(c1ccc4c(c1)C(C)(C)c1ccccc1-4)c1cc4c(cc1B3N(c1ccc(-c3ccccc3)cc1)c1cc3ccccc3cc1-2)-c1ccccc1C4(C)C ; Cc1cc2c3c(c1)N(c1ccc4c(c1)oc1cc5c(cc14)C(C)(C)CCC5(C)C)c1cc4oc5cc6c(cc5c4cc1B3N(c1ccc(-c3ccccc3)cc1)c1cc3ccccc3cc1-2)C(C)(C)CCC6(C)C ; Cc1cc2c3c(c1)N(c1ccc4c(c1)sc1ccccc14)c1cc4sc5ccccc5c4cc1B3N(c1ccc(-c3ccccc3)cc1)c1cc3ccccc3cc1-2] 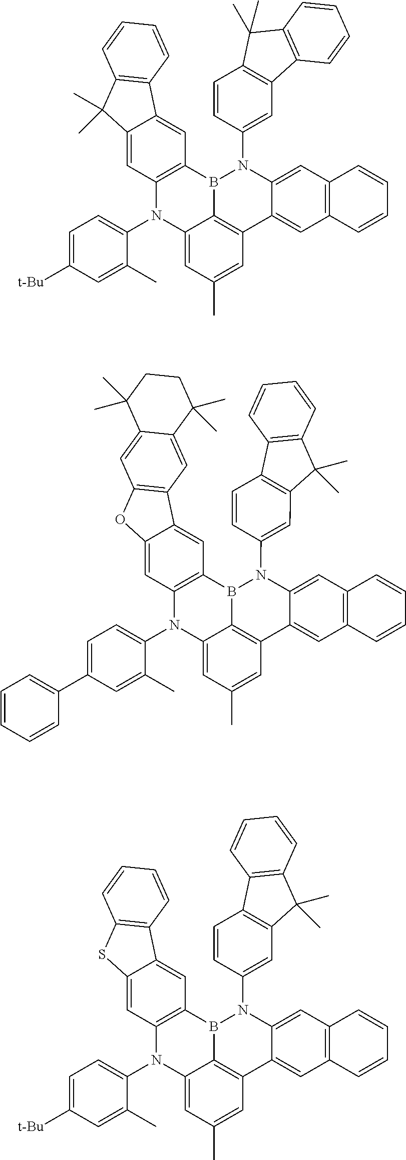 [SMILES: Cc1cc2c3c(c1)N(c1ccc(C(C)(C)C)cc1C)c1cc4c(cc1B3N(c1ccc3c(c1)-c1ccccc1C3(C)C)c1cc3ccccc3cc1-2)-c1ccccc1C4(C)C ; Cc1cc2c3c(c1)N(c1ccc(-c4ccccc4)cc1C)c1cc4oc5cc6c(cc5c4cc1B3N(c1ccc3c(c1)C(C)(C)c1ccccc1-3)c1cc3ccccc3cc1-2)C(C)(C)CCC6(C)C ; Cc1cc2c3c(c1)N(c1ccc(C(C)(C)C)cc1C)c1cc4sc5ccccc5c4cc1B3N(c1ccc3c(c1)C(C)(C)c1ccccc1-3)c1cc3ccccc3cc1-2] 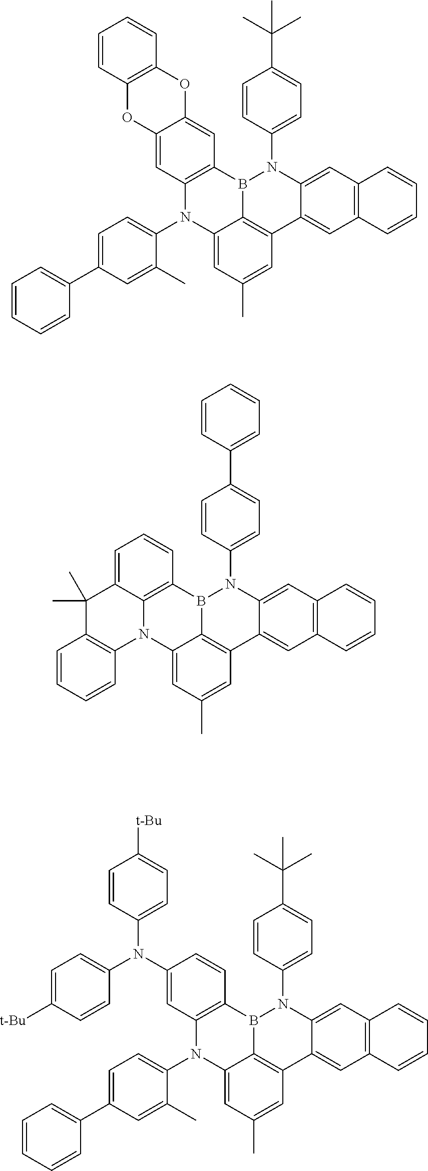 [SMILES: Cc1cc2c3c(c1)N(c1ccc(-c4ccccc4)cc1C)c1cc4c(cc1B3N(c1ccc(C(C)(C)C)cc1)c1cc3ccccc3cc1-2)Oc1ccccc1O4 ; Cc1cc2c3c(c1)N1c4ccccc4C(C)(C)c4cccc(c41)B3N(c1ccc(-c3ccccc3)cc1)c1cc3ccccc3cc1-2 ; Cc1cc2c3c(c1)N(c1ccc(-c4ccccc4)cc1C)c1cc(N(c4ccc(C(C)(C)C)cc4)c4ccc(C(C)(C)C)cc4)ccc1B3N(c1ccc(C(C)(C)C)cc1)c1cc3ccccc3cc1-2] 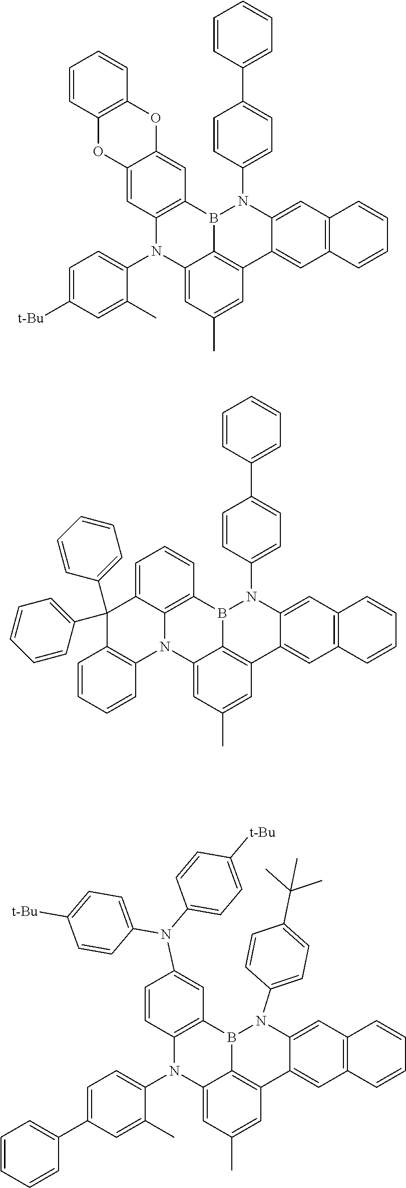 [SMILES: Cc1cc2c3c(c1)N(c1ccc(C(C)(C)C)cc1C)c1cc4c(cc1B3N(c1ccc(-c3ccccc3)cc1)c1cc3ccccc3cc1-2)Oc1ccccc1O4 ; Cc1cc2c3c(c1)N1c4ccccc4C(c4ccccc4)(c4ccccc4)c4cccc(c41)B3N(c1ccc(-c3ccccc3)cc1)c1cc3ccccc3cc1-2 ; Cc1cc2c3c(c1)N(c1ccc(-c4ccccc4)cc1C)c1ccc(N(c4ccc(C(C)(C)C)cc4)c4ccc(C(C)(C)C)cc4)cc1B3N(c1ccc(C(C)(C)C)cc1)c1cc3ccccc3cc1-2] 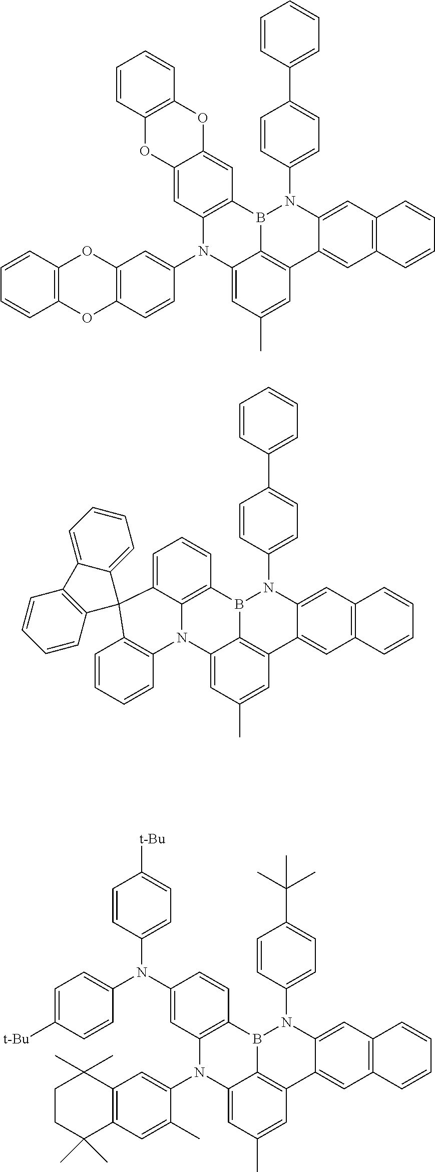 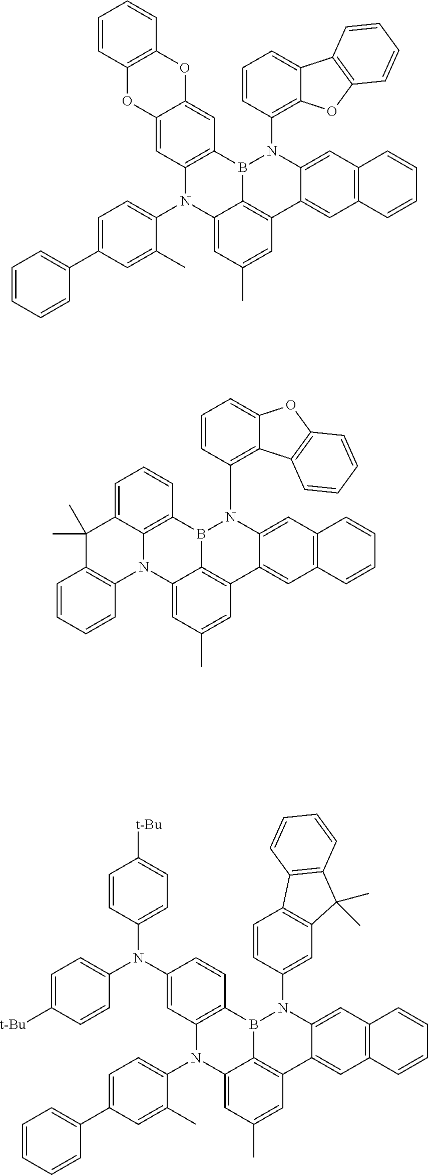 [SMILES: Cc1cc2c3c(c1)N(c1ccc(-c4ccccc4)cc1C)c1cc4c(cc1B3N(c1cccc3c1oc1ccccc13)c1cc3ccccc3cc1-2)Oc1ccccc1O4 ; Cc1cc2c3c(c1)N1c4ccccc4C(C)(C)c4cccc(c41)B3N(c1cccc3oc4ccccc4c13)c1cc3ccccc3cc1-2 ; Cc1cc2c3c(c1)N(c1ccc(-c4ccccc4)cc1C)c1cc(N(c4ccc(C(C)(C)C)cc4)c4ccc(C(C)(C)C)cc4)ccc1B3N(c1ccc3c(c1)C(C)(C)c1ccccc1-3)c1cc3ccccc3cc1-2] 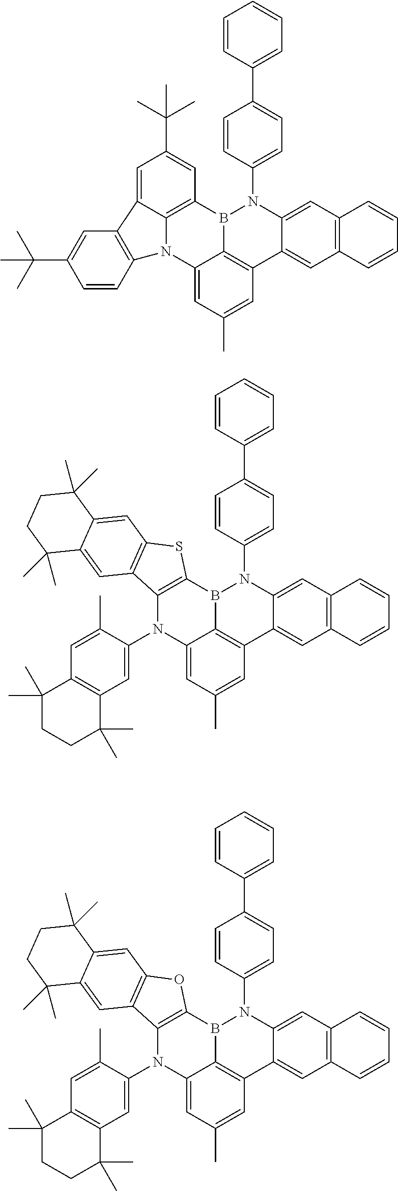 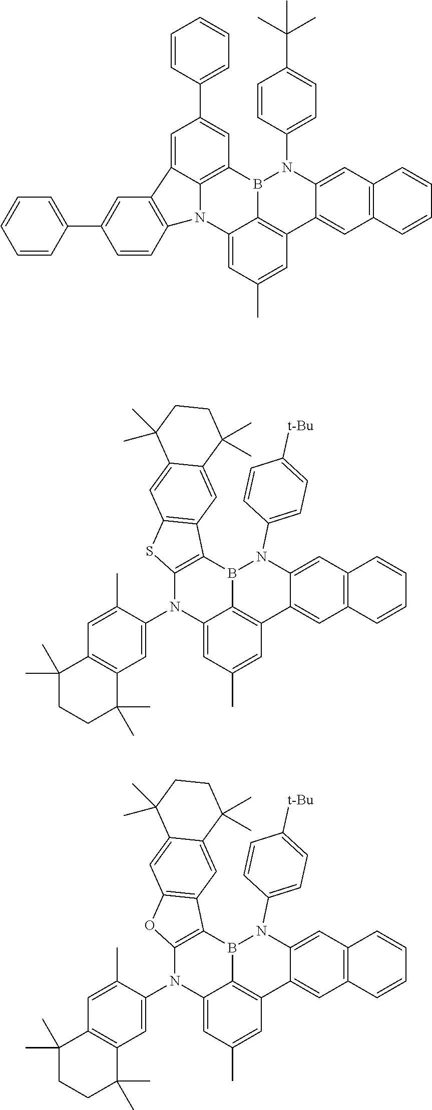 [SMILES: Cc1cc2c3c(c1)-n1c4ccc(-c5ccccc5)cc4c4cc(-c5ccccc5)cc(c41)B3N(c1ccc(C(C)(C)C)cc1)c1cc3ccccc3cc1-2 ; Cc1cc2c3c(c1)N(c1cc4c(cc1C)C(C)(C)CCC4(C)C)c1sc4cc5c(cc4c1B3N(c1ccc(C(C)(C)C)cc1)c1cc3ccccc3cc1-2)C(C)(C)CCC5(C)C ; Cc1cc2c3c(c1)N(c1cc4c(cc1C)C(C)(C)CCC4(C)C)c1oc4cc5c(cc4c1B3N(c1ccc(C(C)(C)C)cc1)c1cc3ccccc3cc1-2)C(C)(C)CCC5(C)C] 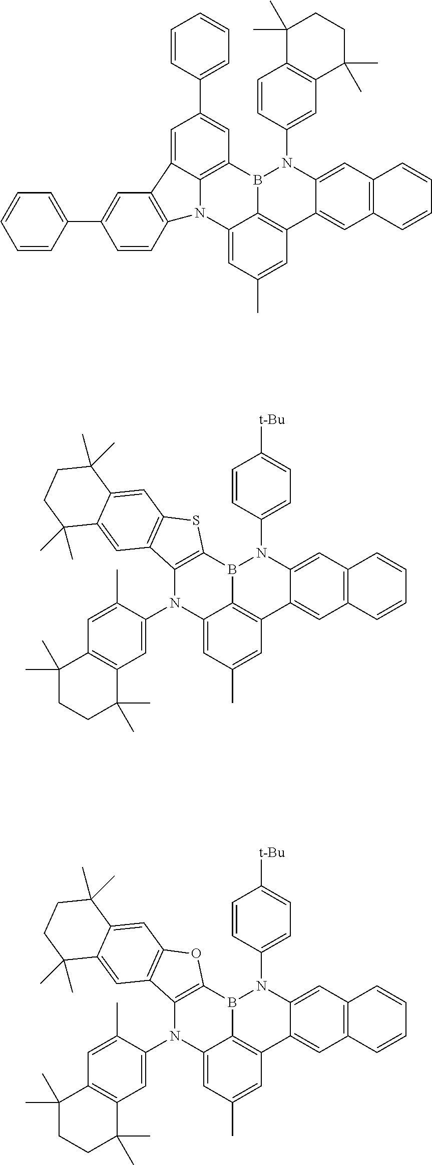 [SMILES: Cc1cc2c3c(c1)-n1c4ccc(-c5ccccc5)cc4c4cc(-c5ccccc5)cc(c41)B3N(c1ccc3c(c1)C(C)(C)CCC3(C)C)c1cc3ccccc3cc1-2 ; Cc1cc2c3c(c1)N(c1cc4c(cc1C)C(C)(C)CCC4(C)C)c1c(sc4cc5c(cc14)C(C)(C)CCC5(C)C)B3N(c1ccc(C(C)(C)C)cc1)c1cc3ccccc3cc1-2 ; Cc1cc2c3c(c1)N(c1cc4c(cc1C)C(C)(C)CCC4(C)C)c1c(oc4cc5c(cc14)C(C)(C)CCC5(C)C)B3N(c1ccc(C(C)(C)C)cc1)c1cc3ccccc3cc1-2] 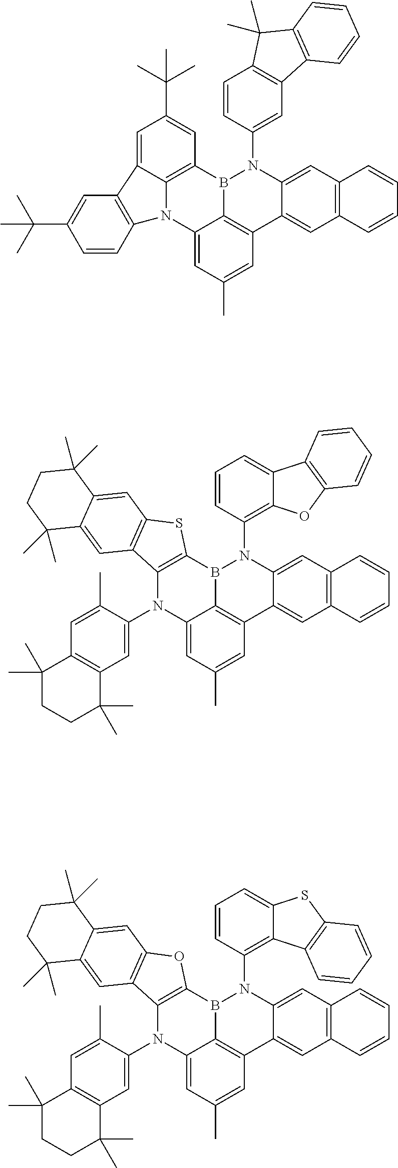 [SMILES: Cc1cc2c3c(c1)-n1c4ccc(C(C)(C)C)cc4c4cc(C(C)(C)C)cc(c41)B3N(c1ccc3c(c1)-c1ccccc1C3(C)C)c1cc3ccccc3cc1-2 ; Cc1cc2c3c(c1)N(c1cc4c(cc1C)C(C)(C)CCC4(C)C)c1c(sc4cc5c(cc14)C(C)(C)CCC5(C)C)B3N(c1cccc3c1oc1ccccc13)c1cc3ccccc3cc1-2 ; Cc1cc2c3c(c1)N(c1cc4c(cc1C)C(C)(C)CCC4(C)C)c1c(oc4cc5c(cc14)C(C)(C)CCC5(C)C)B3N(c1cccc3sc4ccccc4c13)c1cc3ccccc3cc1-2] 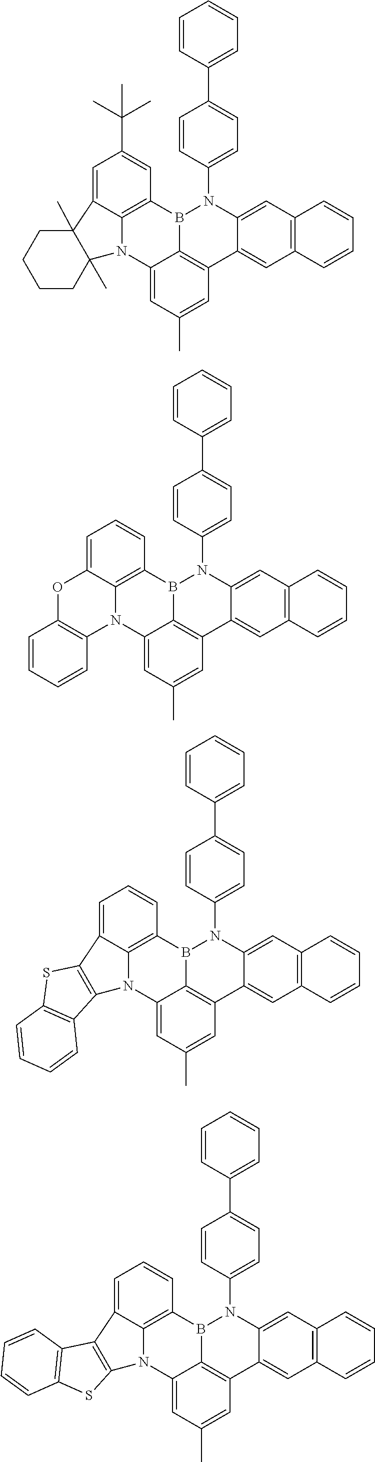 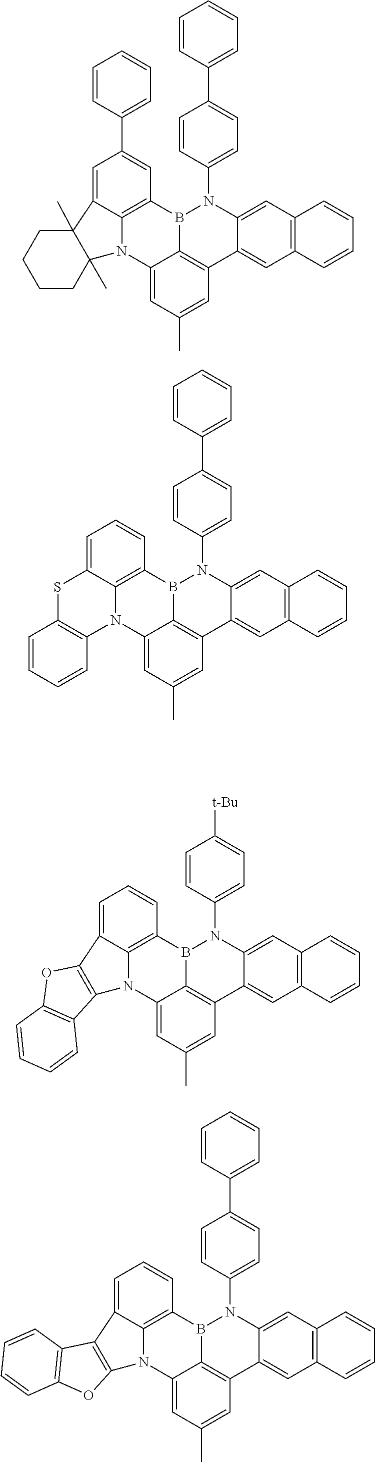 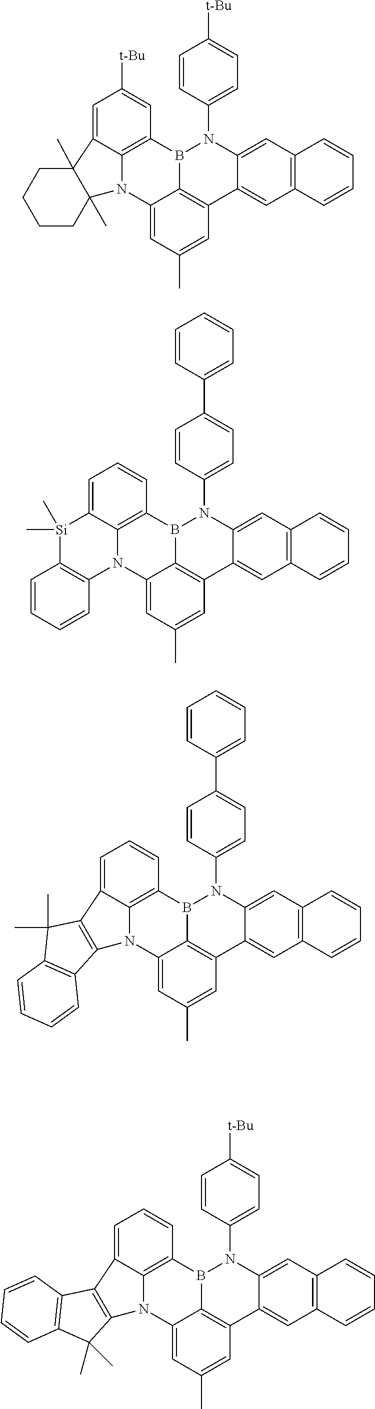 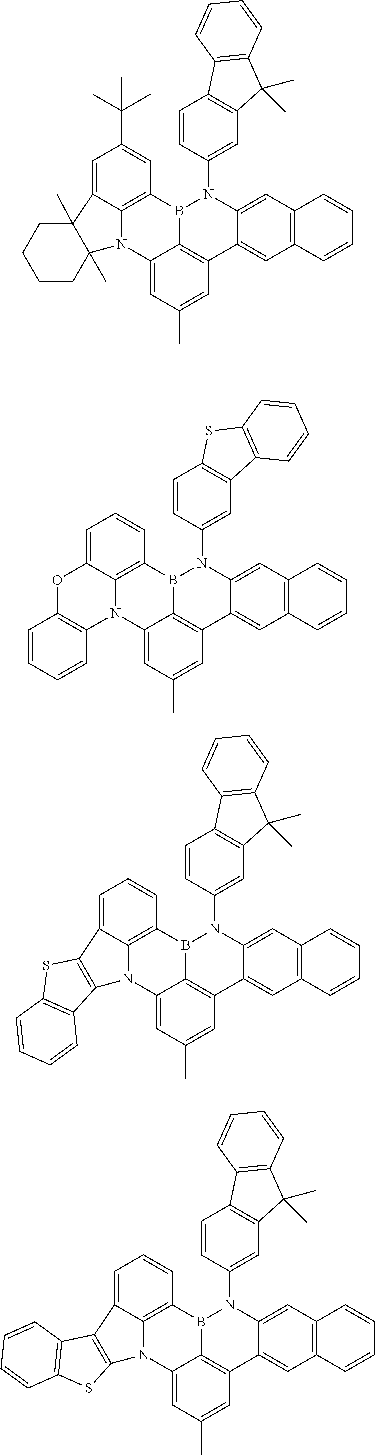 [SMILES: Cc1cc2c3c(c1)N1c4c(cc(C(C)(C)C)cc4C4(C)CCCCC14C)B3N(c1ccc3c(c1)C(C)(C)c1ccccc1-3)c1cc3ccccc3cc1-2 ; Cc1cc2c3c(c1)N1c4ccccc4Oc4cccc(c41)B3N(c1ccc3sc4ccccc4c3c1)c1cc3ccccc3cc1-2 ; Cc1cc2c3c(c1)-n1c4c(cccc4c4sc5ccccc5c41)B3N(c1ccc3c(c1)C(C)(C)c1ccccc1-3)c1cc3ccccc3cc1-2 ; Cc1cc2c3c(c1)-n1c4sc5ccccc5c4c4cccc(c41)B3N(c1ccc3c(c1)C(C)(C)c1ccccc1-3)c1cc3ccccc3cc1-2] 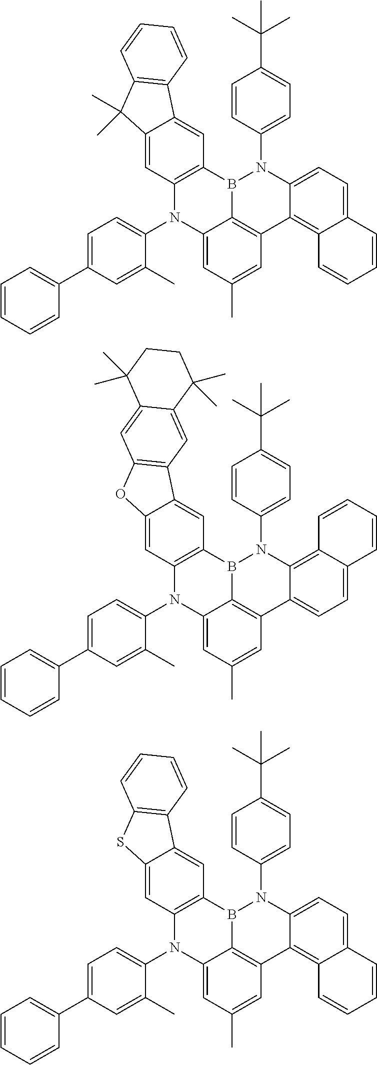 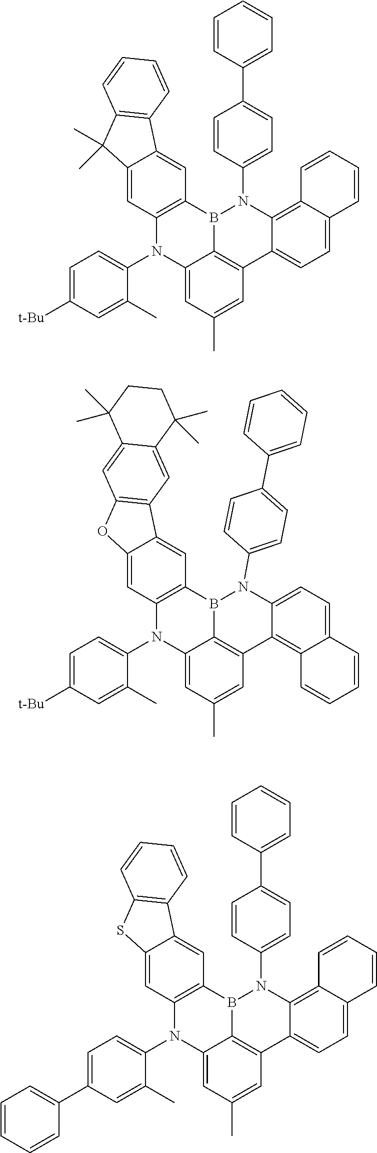 [SMILES: Cc1cc2c3c(c1)N(c1ccc(C(C)(C)C)cc1C)c1cc4c(cc1B3N(c1ccc(-c3ccccc3)cc1)c1c-2ccc2ccccc12)-c1ccccc1C4(C)C ; Cc1cc2c3c(c1)N(c1ccc(C(C)(C)C)cc1C)c1cc4oc5cc6c(cc5c4cc1B3N(c1ccc(-c3ccccc3)cc1)c1ccc3ccccc3c1-2)C(C)(C)CCC6(C)C ; Cc1cc2c3c(c1)N(c1ccc(-c4ccccc4)cc1C)c1cc4sc5ccccc5c4cc1B3N(c1ccc(-c3ccccc3)cc1)c1c-2ccc2ccccc12] 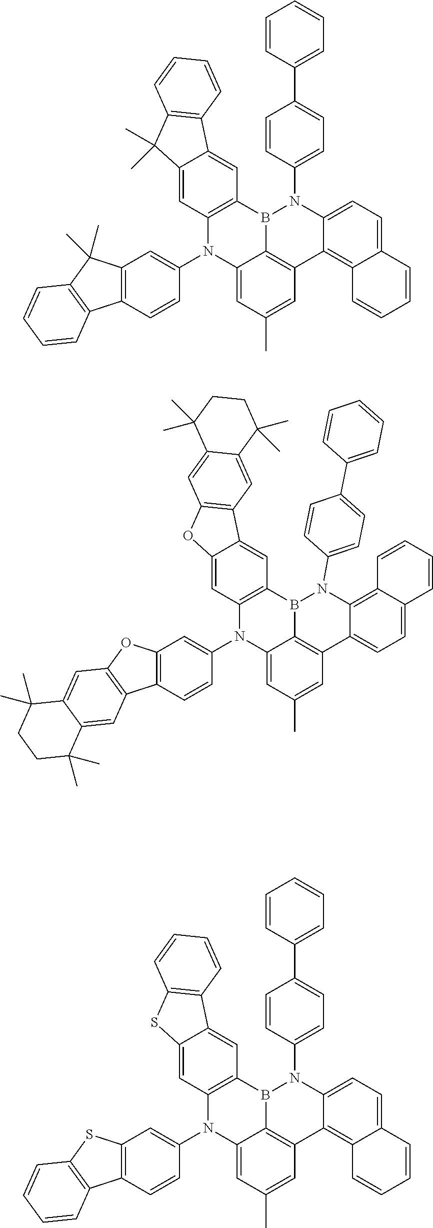 [SMILES: Cc1cc2c3c(c1)N(c1ccc4c(c1)C(C)(C)c1ccccc1-4)c1cc4c(cc1B3N(c1ccc(-c3ccccc3)cc1)c1ccc3ccccc3c1-2)-c1ccccc1C4(C)C ; Cc1cc2c3c(c1)N(c1ccc4c(c1)oc1cc5c(cc14)C(C)(C)CCC5(C)C)c1cc4oc5cc6c(cc5c4cc1B3N(c1ccc(-c3ccccc3)cc1)c1c-2ccc2ccccc12)C(C)(C)CCC6(C)C ; Cc1cc2c3c(c1)N(c1ccc4c(c1)sc1ccccc14)c1cc4sc5ccccc5c4cc1B3N(c1ccc(-c3ccccc3)cc1)c1ccc3ccccc3c1-2] 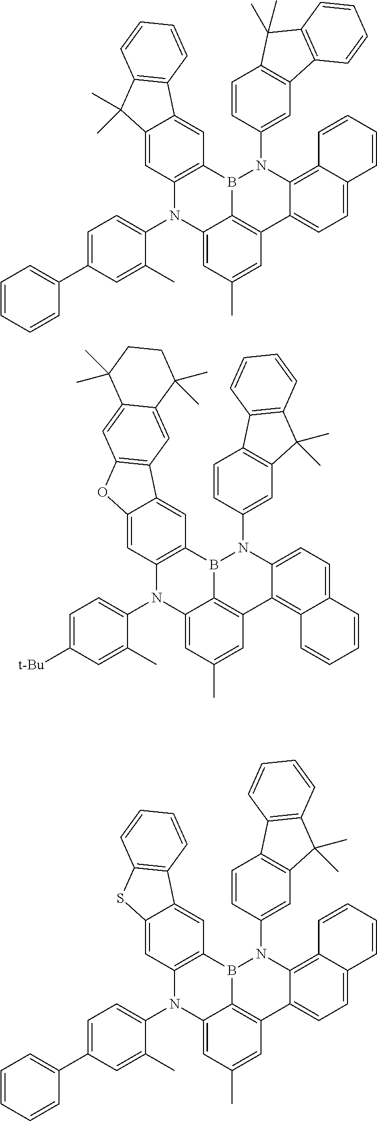 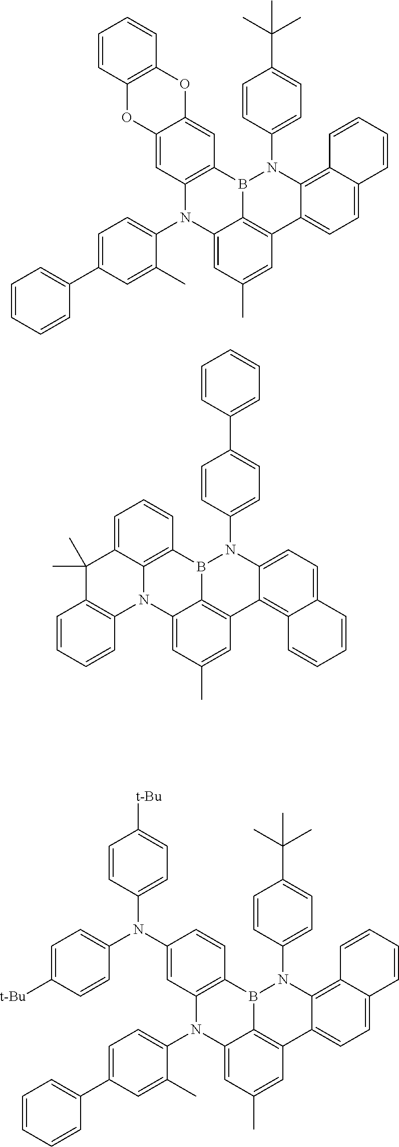 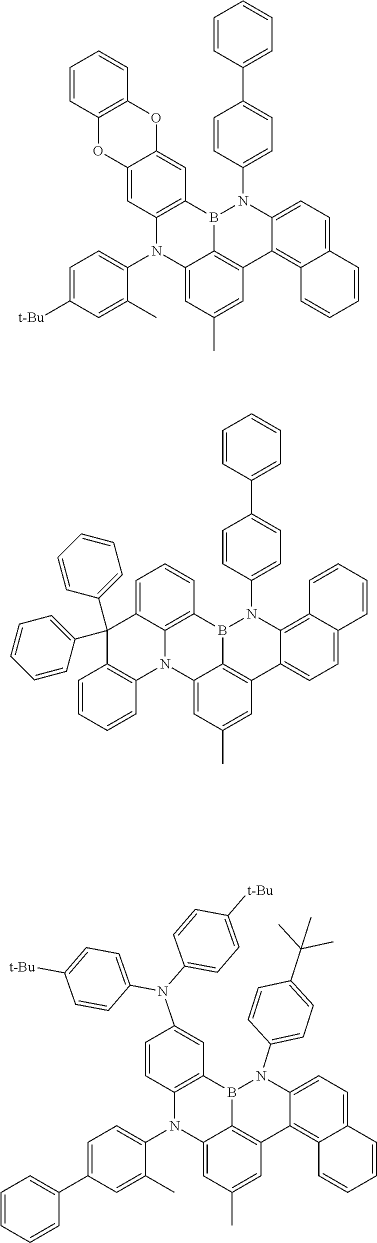 [SMILES: Cc1cc2c3c(c1)N(c1ccc(C(C)(C)C)cc1C)c1cc4c(cc1B3N(c1ccc(-c3ccccc3)cc1)c1ccc3ccccc3c1-2)Oc1ccccc1O4 ; Cc1cc2c3c(c1)N1c4ccccc4C(c4ccccc4)(c4ccccc4)c4cccc(c41)B3N(c1ccc(-c3ccccc3)cc1)c1c-2ccc2ccccc12 ; Cc1cc2c3c(c1)N(c1ccc(-c4ccccc4)cc1C)c1ccc(N(c4ccc(C(C)(C)C)cc4)c4ccc(C(C)(C)C)cc4)cc1B3N(c1ccc(C(C)(C)C)cc1)c1ccc3ccccc3c1-2] 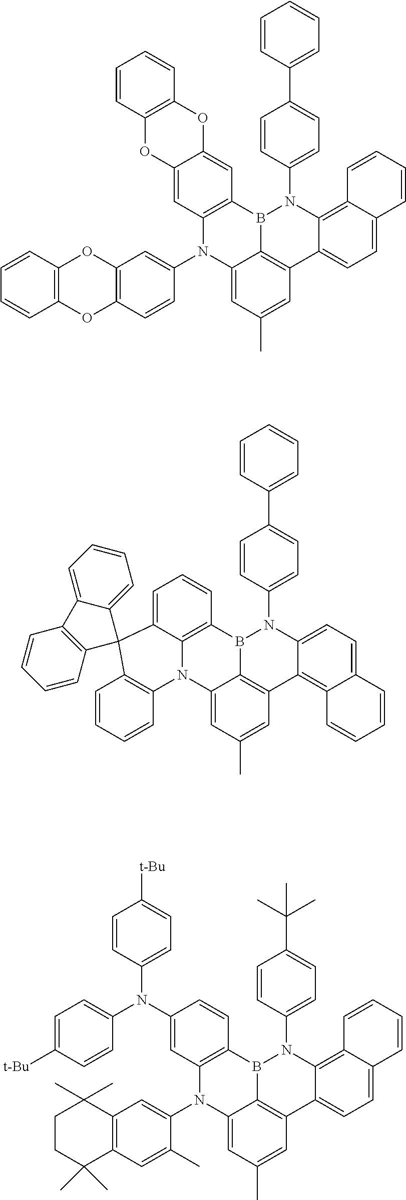 [SMILES: Cc1cc2c3c(c1)N(c1ccc4c(c1)Oc1ccccc1O4)c1cc4c(cc1B3N(c1ccc(-c3ccccc3)cc1)c1c-2ccc2ccccc12)Oc1ccccc1O4 ; Cc1cc2c3c(c1)N1c4ccccc4C4(c5ccccc5-c5ccccc54)c4cccc(c41)B3N(c1ccc(-c3ccccc3)cc1)c1ccc3ccccc3c1-2 ; Cc1cc2c3c(c1)N(c1cc4c(cc1C)C(C)(C)CCC4(C)C)c1cc(N(c4ccc(C(C)(C)C)cc4)c4ccc(C(C)(C)C)cc4)ccc1B3N(c1ccc(C(C)(C)C)cc1)c1c-2ccc2ccccc12] 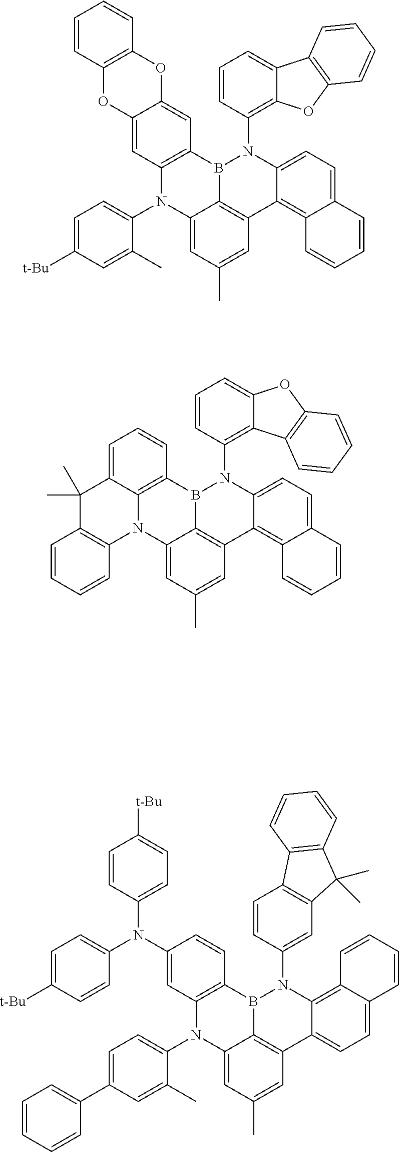 [SMILES: Cc1cc2c3c(c1)N(c1ccc(C(C)(C)C)cc1C)c1cc4c(cc1B3N(c1cccc3c1oc1ccccc13)c1ccc3ccccc3c1-2)Oc1ccccc1O4 ; Cc1cc2c3c(c1)N1c4ccccc4C(C)(C)c4cccc(c41)B3N(c1cccc3oc4ccccc4c13)c1ccc3ccccc3c1-2 ; Cc1cc2c3c(c1)N(c1ccc(-c4ccccc4)cc1C)c1cc(N(c4ccc(C(C)(C)C)cc4)c4ccc(C(C)(C)C)cc4)ccc1B3N(c1ccc3c(c1)C(C)(C)c1ccccc1-3)c1c-2ccc2ccccc12] 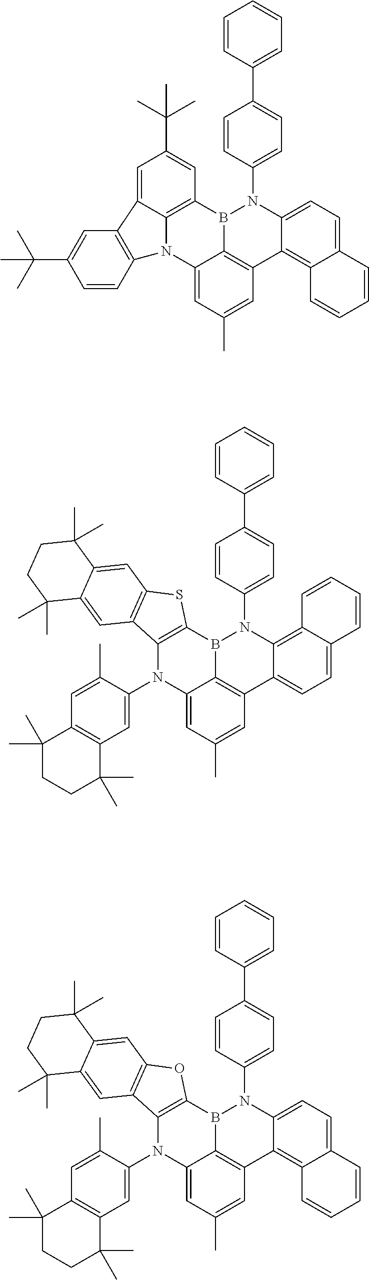 [SMILES: Cc1cc2c3c(c1)-n1c4ccc(C(C)(C)C)cc4c4cc(C(C)(C)C)cc(c41)B3N(c1ccc(-c3ccccc3)cc1)c1ccc3ccccc3c1-2 ; Cc1cc2c3c(c1)N(c1cc4c(cc1C)C(C)(C)CCC4(C)C)c1c(sc4cc5c(cc14)C(C)(C)CCC5(C)C)B3N(c1ccc(-c3ccccc3)cc1)c1c-2ccc2ccccc12 ; Cc1cc2c3c(c1)N(c1cc4c(cc1C)C(C)(C)CCC4(C)C)c1c(oc4cc5c(cc14)C(C)(C)CCC5(C)C)B3N(c1ccc(-c3ccccc3)cc1)c1ccc3ccccc3c1-2] 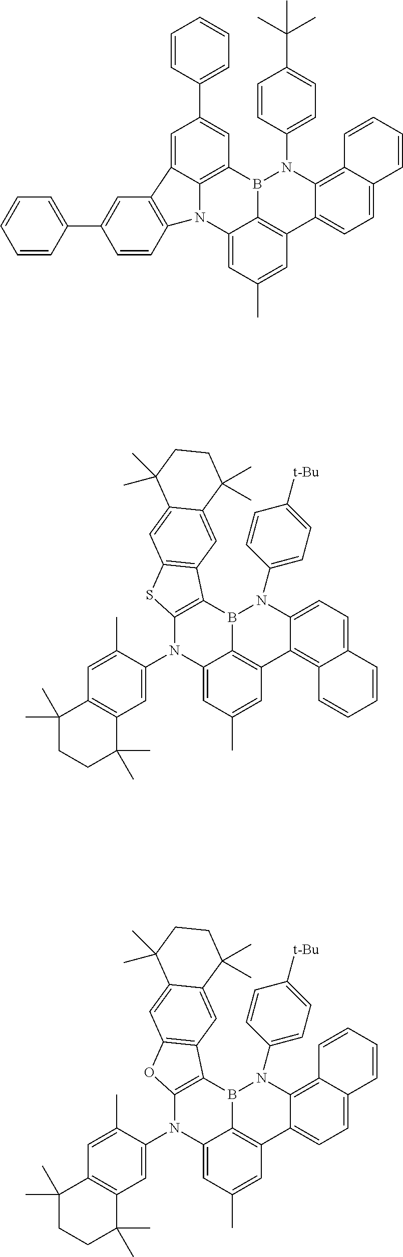 [SMILES: Cc1cc2c3c(c1)-n1c4ccc(-c5ccccc5)cc4c4cc(-c5ccccc5)cc(c41)B3N(c1ccc(C(C)(C)C)cc1)c1c-2ccc2ccccc12 ; Cc1cc2c3c(c1)N(c1cc4c(cc1C)C(C)(C)CCC4(C)C)c1sc4cc5c(cc4c1B3N(c1ccc(C(C)(C)C)cc1)c1ccc3ccccc3c1-2)C(C)(C)CCC5(C)C ; Cc1cc2c3c(c1)N(c1cc4c(cc1C)C(C)(C)CCC4(C)C)c1oc4cc5c(cc4c1B3N(c1ccc(C(C)(C)C)cc1)c1c-2ccc2ccccc12)C(C)(C)CCC5(C)C] 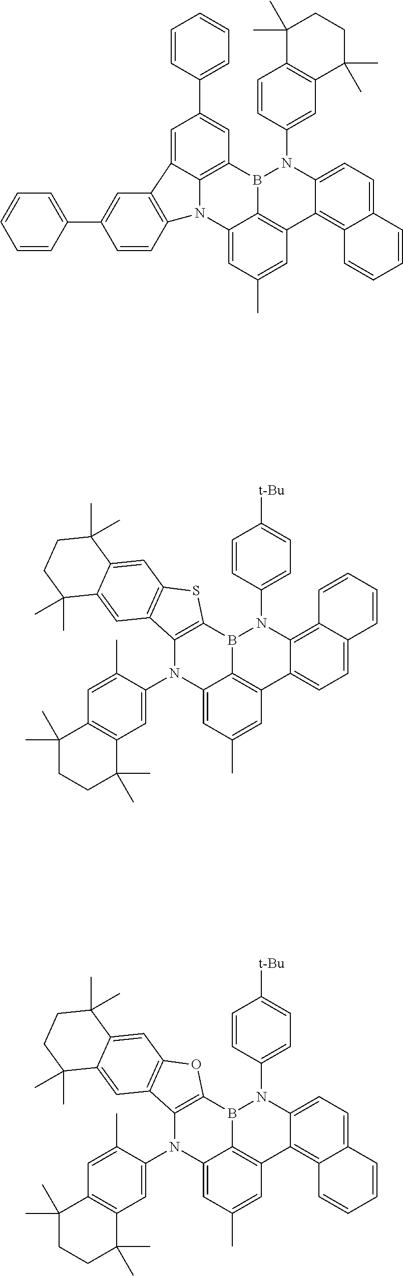 [SMILES: Cc1cc2c3c(c1)-n1c4ccc(-c5ccccc5)cc4c4cc(-c5ccccc5)cc(c41)B3N(c1ccc3c(c1)C(C)(C)CCC3(C)C)c1ccc3ccccc3c1-2 ; Cc1cc2c3c(c1)N(c1cc4c(cc1C)C(C)(C)CCC4(C)C)c1c(sc4cc5c(cc14)C(C)(C)CCC5(C)C)B3N(c1ccc(C(C)(C)C)cc1)c1c-2ccc2ccccc12 ; Cc1cc2c3c(c1)N(c1cc4c(cc1C)C(C)(C)CCC4(C)C)c1c(oc4cc5c(cc14)C(C)(C)CCC5(C)C)B3N(c1ccc(C(C)(C)C)cc1)c1ccc3ccccc3c1-2] 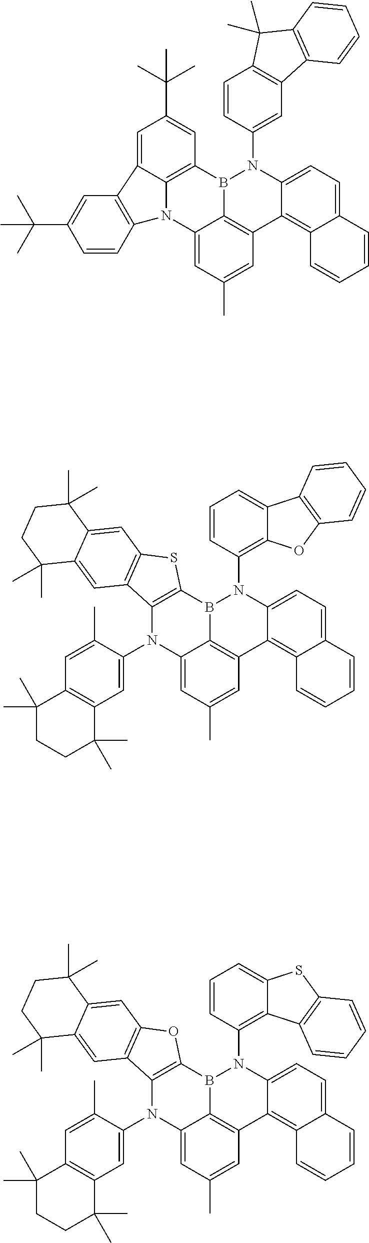 [SMILES: Cc1cc2c3c(c1)-n1c4ccc(C(C)(C)C)cc4c4cc(C(C)(C)C)cc(c41)B3N(c1ccc3c(c1)-c1ccccc1C3(C)C)c1ccc3ccccc3c1-2 ; Cc1cc2c3c(c1)N(c1cc4c(cc1C)C(C)(C)CCC4(C)C)c1c(sc4cc5c(cc14)C(C)(C)CCC5(C)C)B3N(c1cccc3c1oc1ccccc13)c1ccc3ccccc3c1-2 ; Cc1cc2c3c(c1)N(c1cc4c(cc1C)C(C)(C)CCC4(C)C)c1c(oc4cc5c(cc14)C(C)(C)CCC5(C)C)B3N(c1cccc3sc4ccccc4c13)c1ccc3ccccc3c1-2] 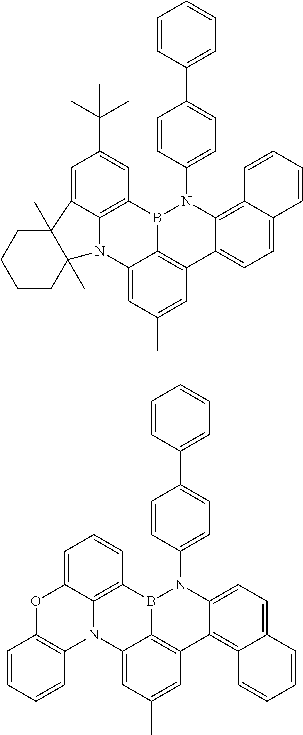 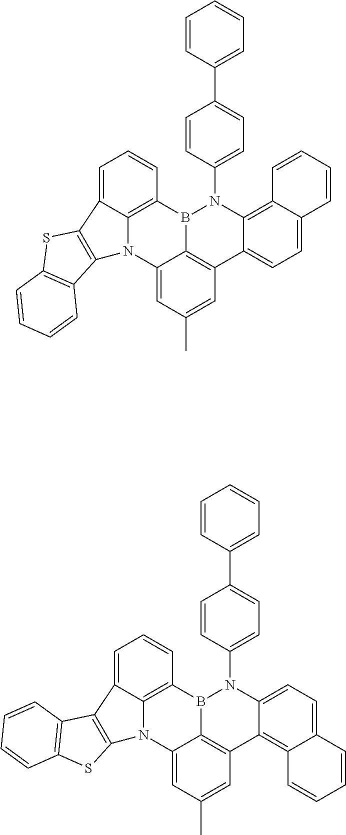 [SMILES: Cc1cc2c3c(c1)-n1c4c(cccc4c4sc5ccccc5c41)B3N(c1ccc(-c3ccccc3)cc1)c1c-2ccc2ccccc12 ; Cc1cc2c3c(c1)-n1c4sc5ccccc5c4c4cccc(c41)B3N(c1ccc(-c3ccccc3)cc1)c1ccc3ccccc3c1-2] 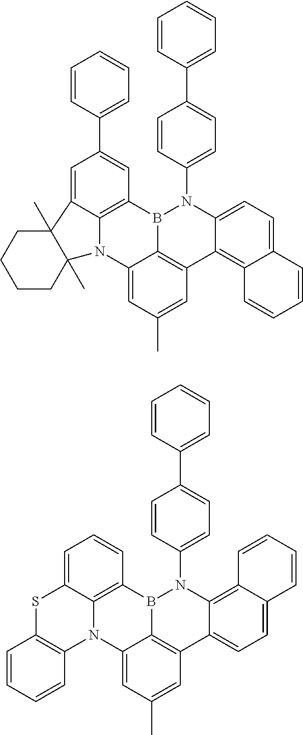 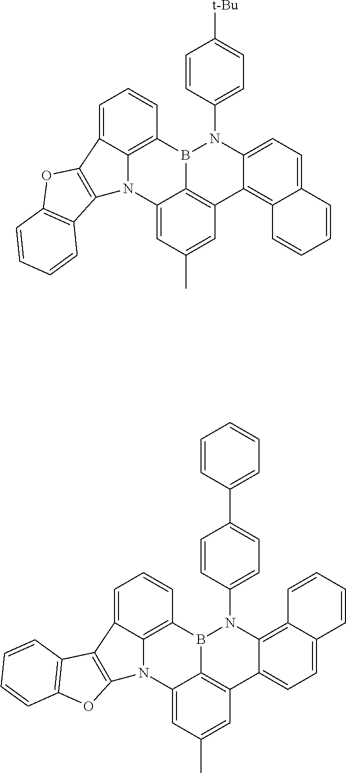 [SMILES: Cc1cc2c3c(c1)-n1c4c(cccc4c4oc5ccccc5c41)B3N(c1ccc(C(C)(C)C)cc1)c1ccc3ccccc3c1-2 ; Cc1cc2c3c(c1)-n1c4oc5ccccc5c4c4cccc(c41)B3N(c1ccc(-c3ccccc3)cc1)c1c-2ccc2ccccc12] 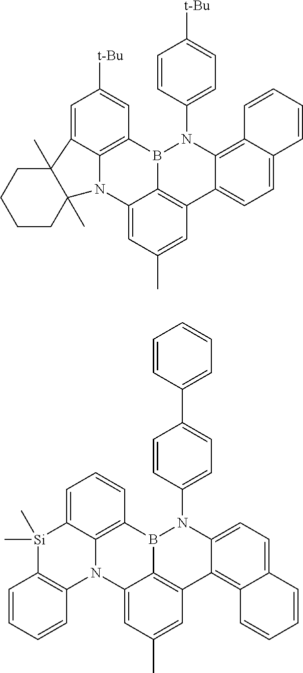 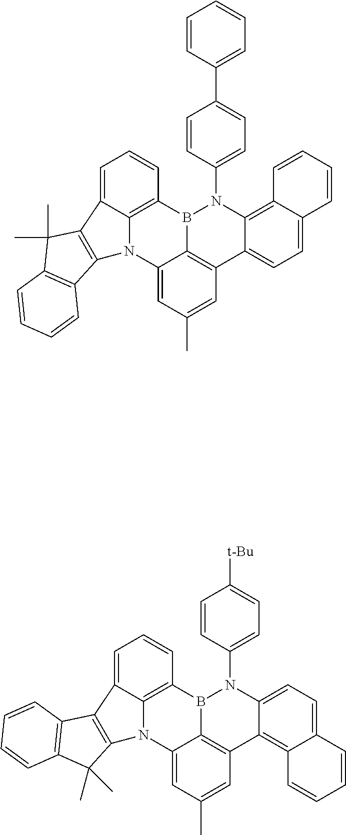 [SMILES: Cc1cc2c3c(c1)-n1c4c(c5cccc(c51)B3N(c1ccc(-c3ccccc3)cc1)c1c-2ccc2ccccc12)C(C)(C)c1ccccc1-4 ; Cc1cc2c3c(c1)-n1c4c(c5cccc(c51)B3N(c1ccc(C(C)(C)C)cc1)c1ccc3ccccc3c1-2)-c1ccccc1C4(C)C] 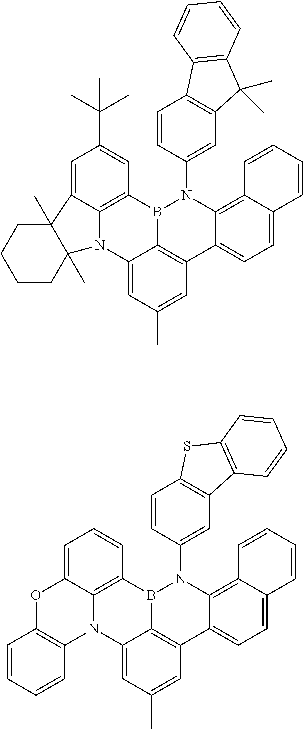 [SMILES: Cc1cc2c3c(c1)N1c4c(cc(C(C)(C)C)cc4C4(C)CCCCC14C)B3N(c1ccc3c(c1)C(C)(C)c1ccccc1-3)c1c-2ccc2ccccc12 ; Cc1cc2c3c(c1)N1c4ccccc4Oc4cccc(c41)B3N(c1ccc3sc4ccccc4c3c1)c1c-2ccc2ccccc12] 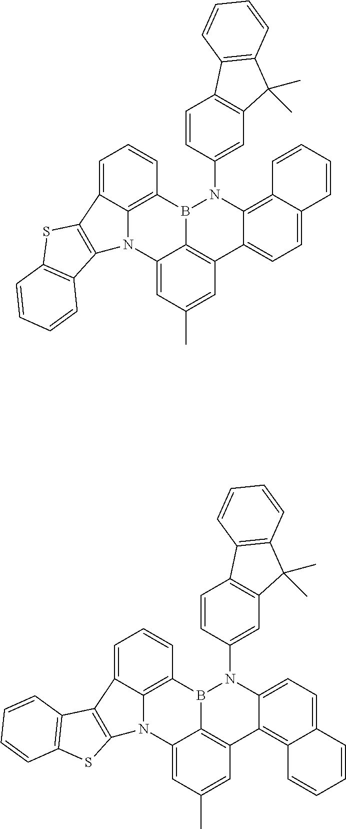 [SMILES: Cc1cc2c3c(c1)-n1c4c(cccc4c4sc5ccccc5c41)B3N(c1ccc3c(c1)C(C)(C)c1ccccc1-3)c1c-2ccc2ccccc12 ; Cc1cc2c3c(c1)-n1c4sc5ccccc5c4c4cccc(c41)B3N(c1ccc3c(c1)C(C)(C)c1ccccc1-3)c1ccc3ccccc3c1-2] 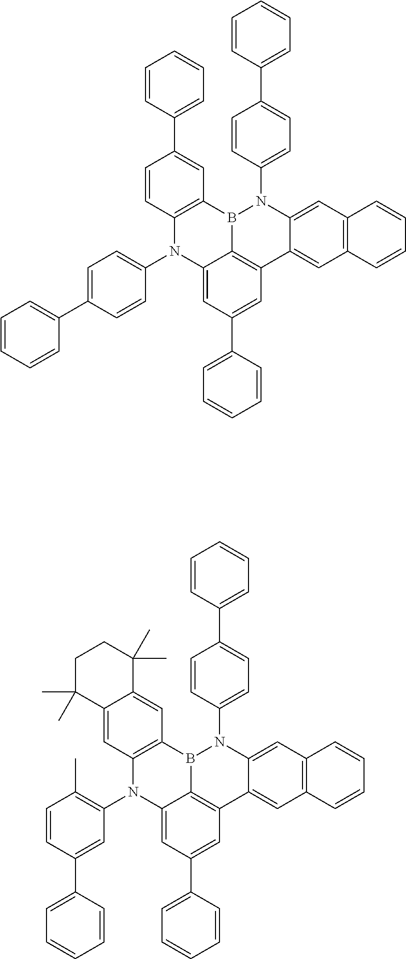 [SMILES: c1ccc(-c2ccc(N3B4c5cc(-c6ccccc6)ccc5N(c5ccc(-c6ccccc6)cc5)c5cc(-c6ccccc6)cc(c54)-c4cc5ccccc5cc43)cc2)cc1 ; Cc1ccc(-c2ccccc2)cc1N1c2cc3c(cc2B2c4c(cc(-c5ccccc5)cc41)-c1cc4ccccc4cc1N2c1ccc(-c2ccccc2)cc1)C(C)(C)CCC3(C)C] 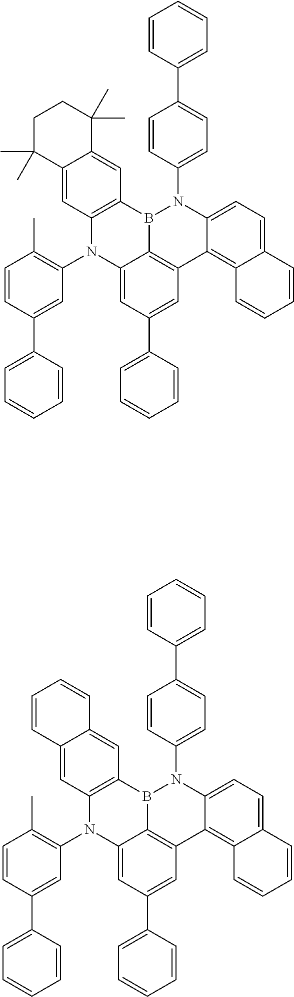 [SMILES: Cc1ccc(-c2ccccc2)cc1N1c2cc3c(cc2B2c4c(cc(-c5ccccc5)cc41)-c1c(ccc4ccccc14)N2c1ccc(-c2ccccc2)cc1)C(C)(C)CCC3(C)C ; Cc1ccc(-c2ccccc2)cc1N1c2cc3ccccc3cc2B2c3c(cc(-c4ccccc4)cc31)-c1c(ccc3ccccc13)N2c1ccc(-c2ccccc2)cc1] 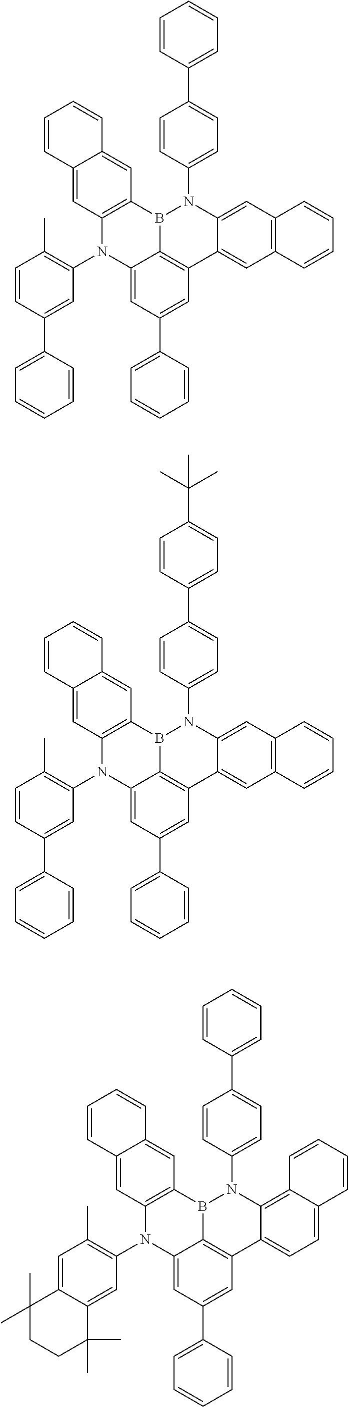 [SMILES: Cc1ccc(-c2ccccc2)cc1N1c2cc3ccccc3cc2B2c3c(cc(-c4ccccc4)cc31)-c1cc3ccccc3cc1N2c1ccc(-c2ccccc2)cc1 ; Cc1ccc(-c2ccccc2)cc1N1c2cc3ccccc3cc2B2c3c(cc(-c4ccccc4)cc31)-c1cc3ccccc3cc1N2c1ccc(-c2ccc(C(C)(C)C)cc2)cc1 ; Cc1cc2c(cc1N1c3cc4ccccc4cc3B3c4c(cc(-c5ccccc5)cc41)-c1ccc4ccccc4c1N3c1ccc(-c3ccccc3)cc1)C(C)(C)CCC2(C)C] 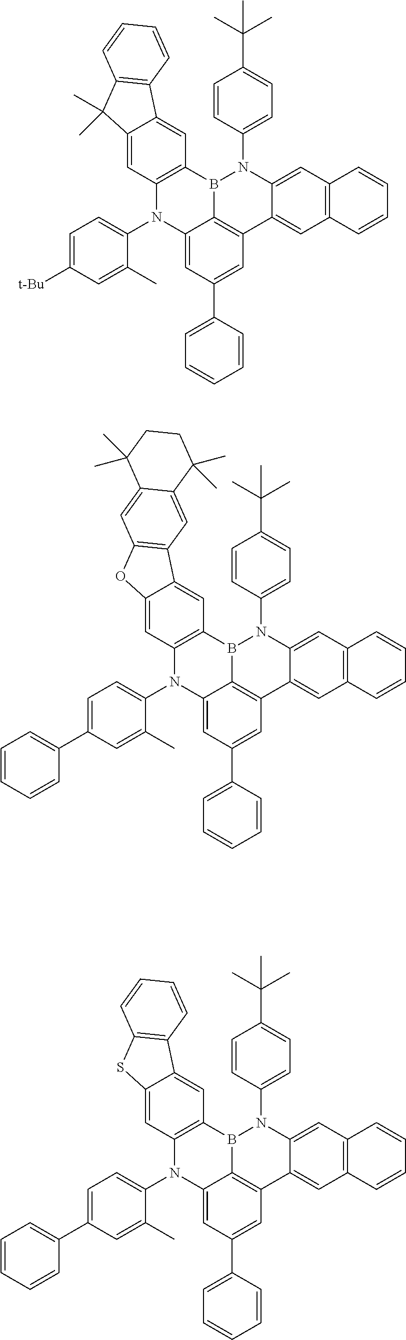 [SMILES: Cc1cc(C(C)(C)C)ccc1N1c2cc3c(cc2B2c4c(cc(-c5ccccc5)cc41)-c1cc4ccccc4cc1N2c1ccc(C(C)(C)C)cc1)-c1ccccc1C3(C)C ; Cc1cc(-c2ccccc2)ccc1N1c2cc3oc4cc5c(cc4c3cc2B2c3c(cc(-c4ccccc4)cc31)-c1cc3ccccc3cc1N2c1ccc(C(C)(C)C)cc1)C(C)(C)CCC5(C)C ; Cc1cc(-c2ccccc2)ccc1N1c2cc3sc4ccccc4c3cc2B2c3c(cc(-c4ccccc4)cc31)-c1cc3ccccc3cc1N2c1ccc(C(C)(C)C)cc1] 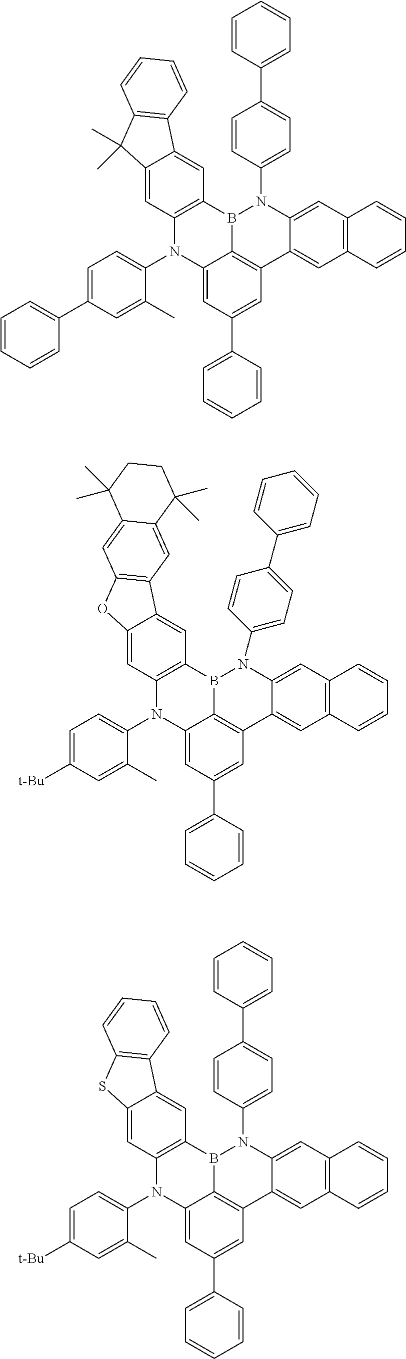 [SMILES: Cc1cc(-c2ccccc2)ccc1N1c2cc3c(cc2B2c4c(cc(-c5ccccc5)cc41)-c1cc4ccccc4cc1N2c1ccc(-c2ccccc2)cc1)-c1ccccc1C3(C)C ; Cc1cc(C(C)(C)C)ccc1N1c2cc3oc4cc5c(cc4c3cc2B2c3c(cc(-c4ccccc4)cc31)-c1cc3ccccc3cc1N2c1ccc(-c2ccccc2)cc1)C(C)(C)CCC5(C)C ; Cc1cc(C(C)(C)C)ccc1N1c2cc3sc4ccccc4c3cc2B2c3c(cc(-c4ccccc4)cc31)-c1cc3ccccc3cc1N2c1ccc(-c2ccccc2)cc1] 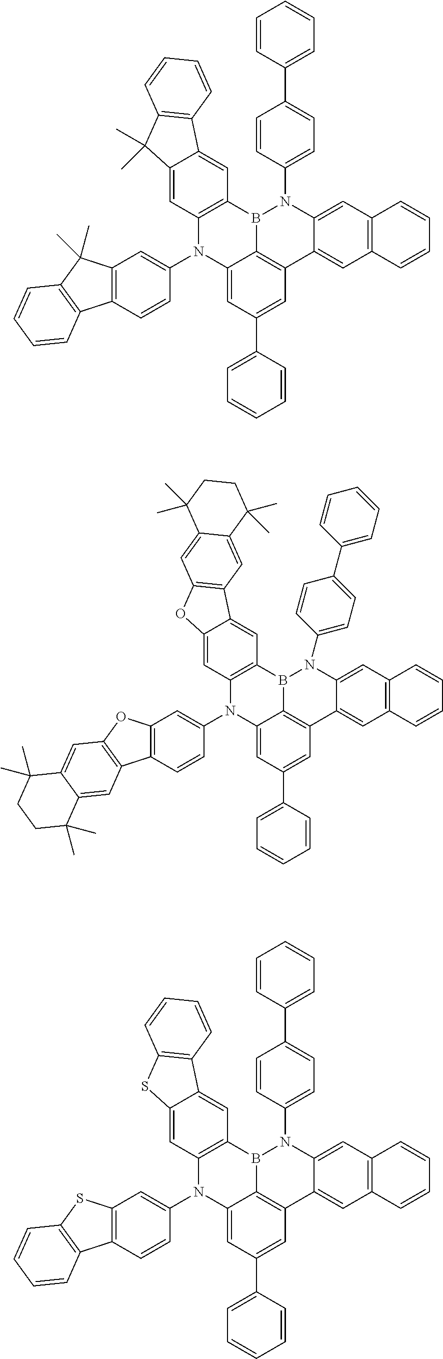 [SMILES: CC1(C)c2ccccc2-c2ccc(N3c4cc5c(cc4B4c6c(cc(-c7ccccc7)cc63)-c3cc6ccccc6cc3N4c3ccc(-c4ccccc4)cc3)-c3ccccc3C5(C)C)cc21 ; CC1(C)CCC(C)(C)c2cc3c(cc21)oc1cc(N2c4cc5oc6cc7c(cc6c5cc4B4c5c(cc(-c6ccccc6)cc52)-c2cc5ccccc5cc2N4c2ccc(-c4ccccc4)cc2)C(C)(C)CCC7(C)C)ccc13 ; c1ccc(-c2ccc(N3B4c5cc6c(cc5N(c5ccc7c(c5)sc5ccccc57)c5cc(-c7ccccc7)cc(c54)-c4cc5ccccc5cc43)sc3ccccc36)cc2)cc1] 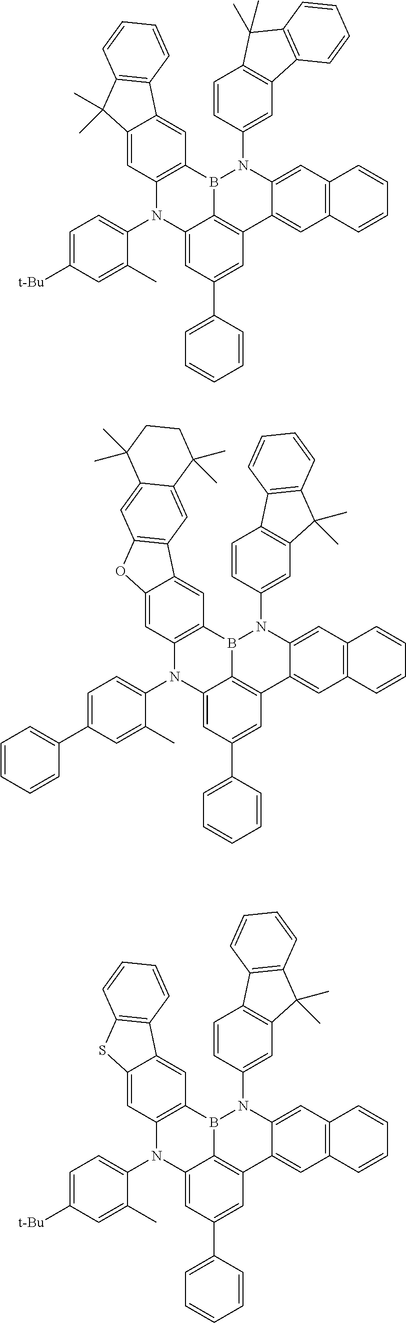 [SMILES: Cc1cc(C(C)(C)C)ccc1N1c2cc3c(cc2B2c4c(cc(-c5ccccc5)cc41)-c1cc4ccccc4cc1N2c1ccc2c(c1)-c1ccccc1C2(C)C)-c1ccccc1C3(C)C ; Cc1cc(-c2ccccc2)ccc1N1c2cc3oc4cc5c(cc4c3cc2B2c3c(cc(-c4ccccc4)cc31)-c1cc3ccccc3cc1N2c1ccc2c(c1)C(C)(C)c1ccccc1-2)C(C)(C)CCC5(C)C ; Cc1cc(C(C)(C)C)ccc1N1c2cc3sc4ccccc4c3cc2B2c3c(cc(-c4ccccc4)cc31)-c1cc3ccccc3cc1N2c1ccc2c(c1)C(C)(C)c1ccccc1-2] 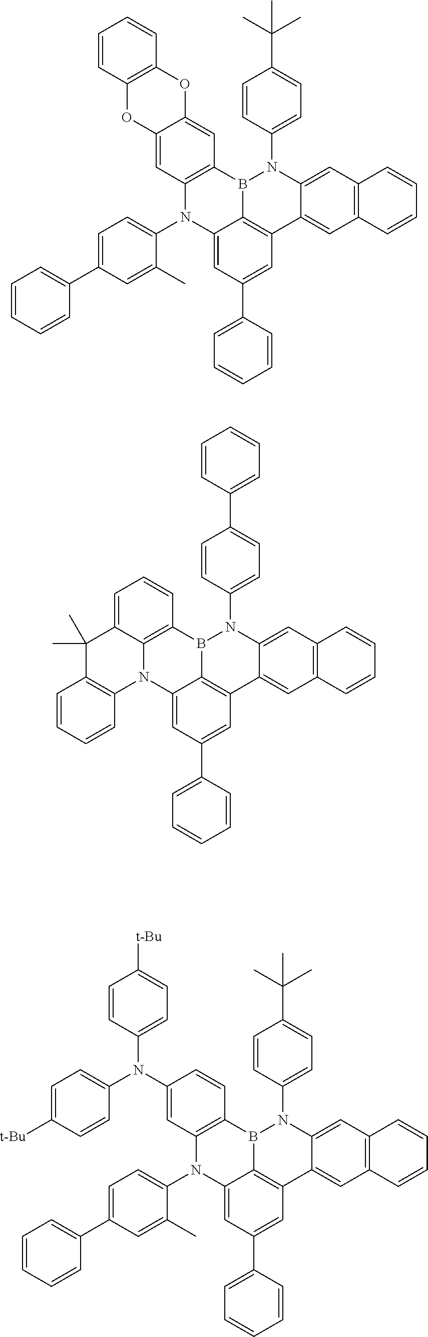 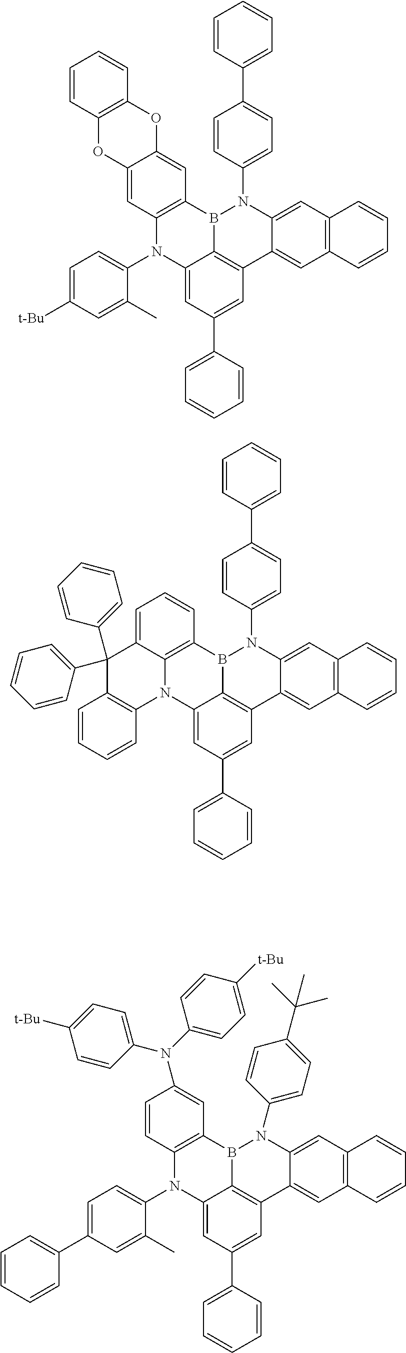 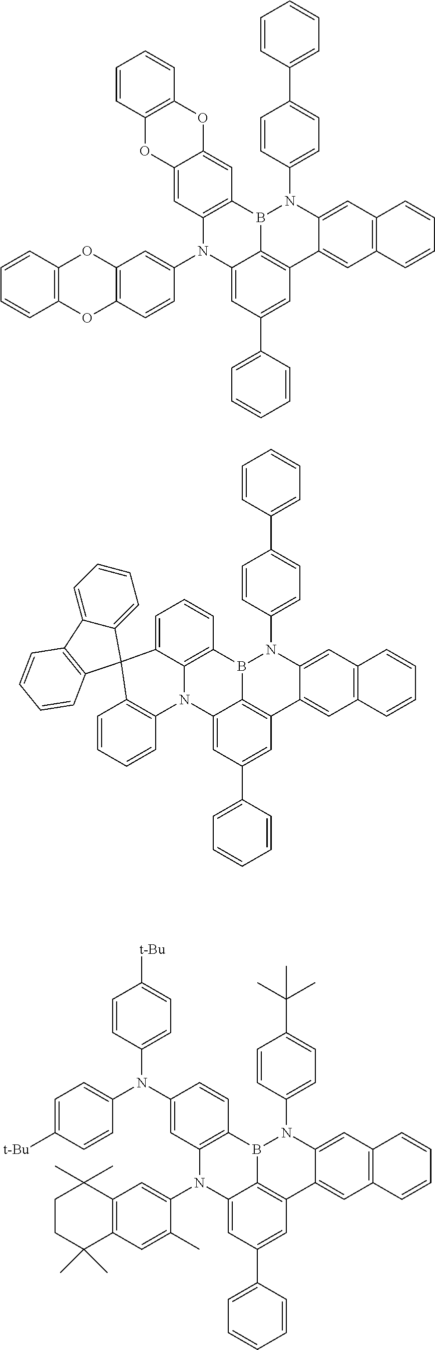 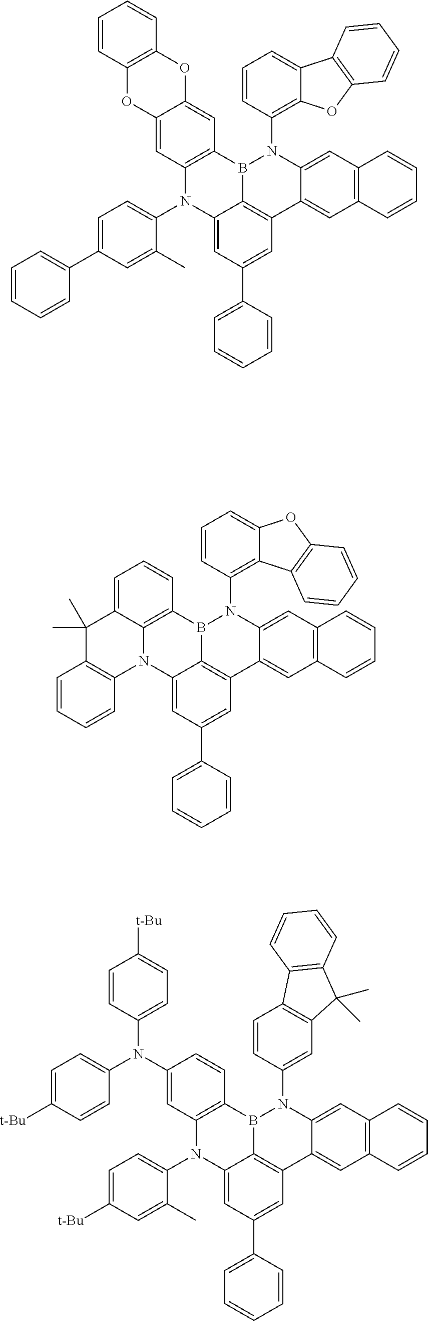 [SMILES: Cc1cc(-c2ccccc2)ccc1N1c2cc3c(cc2B2c4c(cc(-c5ccccc5)cc41)-c1cc4ccccc4cc1N2c1cccc2c1oc1ccccc12)Oc1ccccc1O3 ; CC1(C)c2ccccc2N2c3cc(-c4ccccc4)cc4c3B(c3cccc1c32)N(c1cccc2oc3ccccc3c12)c1cc2ccccc2cc1-4 ; Cc1cc(C(C)(C)C)ccc1N1c2cc(N(c3ccc(C(C)(C)C)cc3)c3ccc(C(C)(C)C)cc3)ccc2B2c3c(cc(-c4ccccc4)cc31)-c1cc3ccccc3cc1N2c1ccc2c(c1)C(C)(C)c1ccccc1-2] 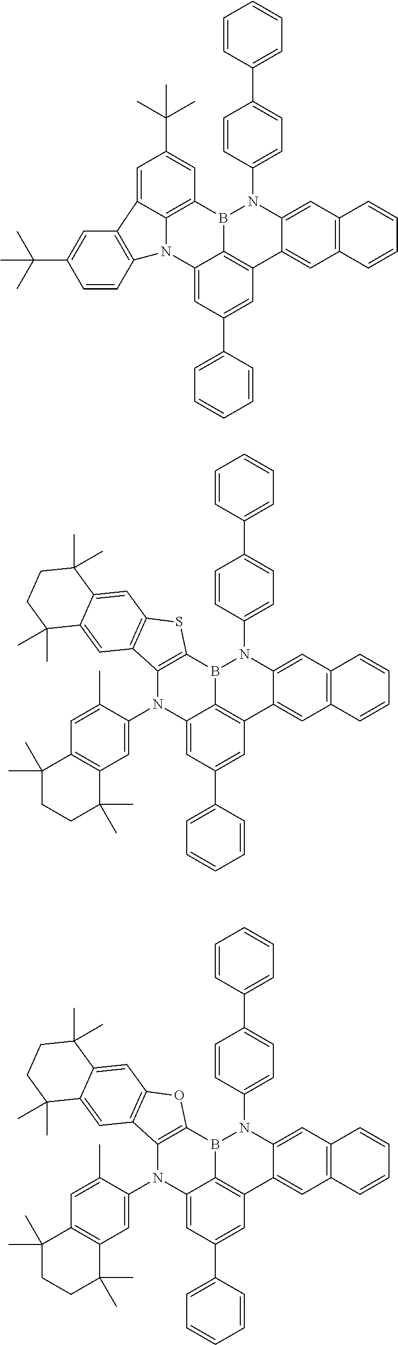 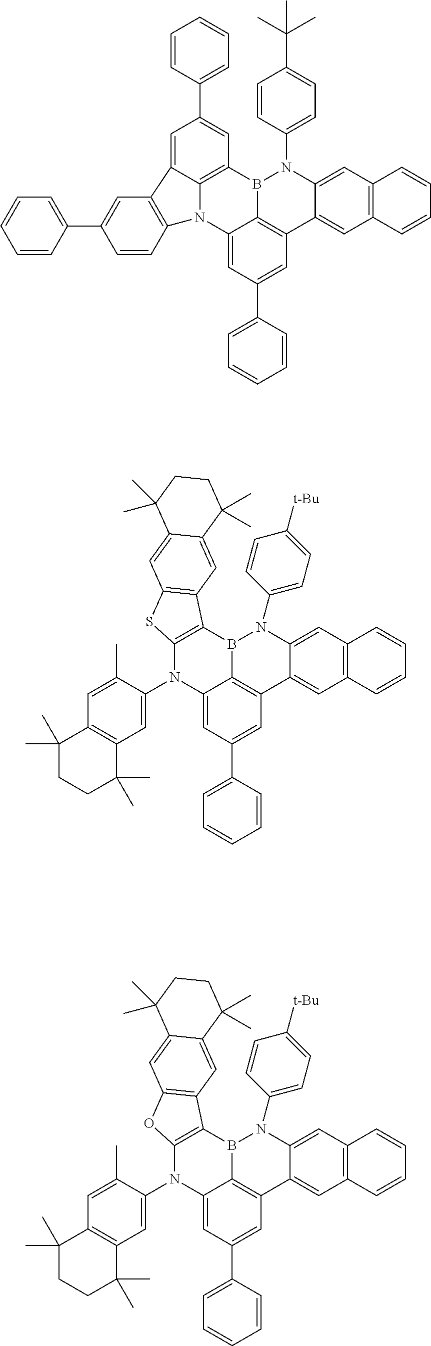 [SMILES: CC(C)(C)c1ccc(N2B3c4c(cc(-c5ccccc5)cc4-n4c5ccc(-c6ccccc6)cc5c5cc(-c6ccccc6)cc3c54)-c3cc4ccccc4cc32)cc1 ; Cc1cc2c(cc1N1c3cc(-c4ccccc4)cc4c3B(c3c1sc1cc5c(cc31)C(C)(C)CCC5(C)C)N(c1ccc(C(C)(C)C)cc1)c1cc3ccccc3cc1-4)C(C)(C)CCC2(C)C ; Cc1cc2c(cc1N1c3cc(-c4ccccc4)cc4c3B(c3c1oc1cc5c(cc31)C(C)(C)CCC5(C)C)N(c1ccc(C(C)(C)C)cc1)c1cc3ccccc3cc1-4)C(C)(C)CCC2(C)C] 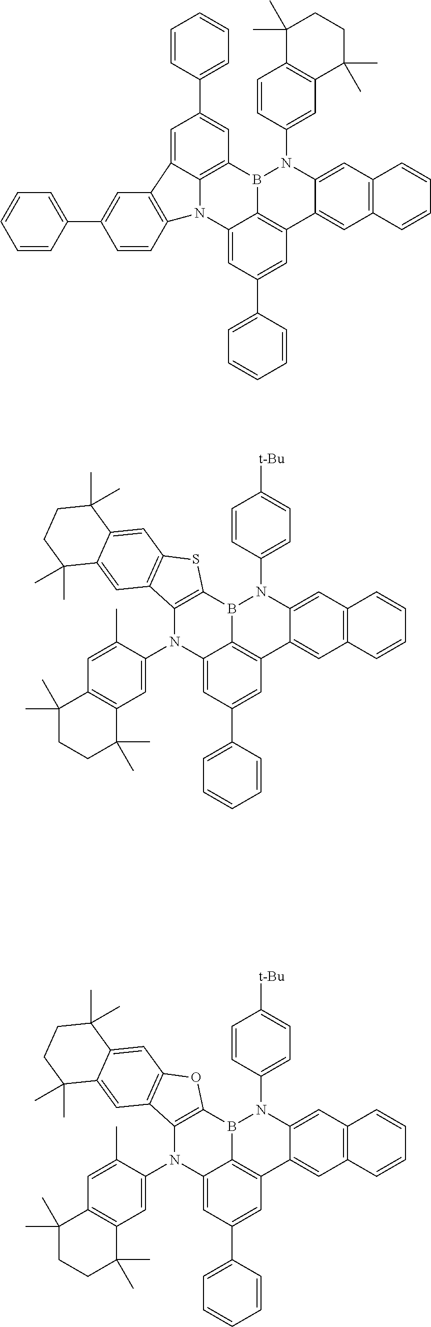 [SMILES: CC1(C)CCC(C)(C)c2cc(N3B4c5c(cc(-c6ccccc6)cc5-n5c6ccc(-c7ccccc7)cc6c6cc(-c7ccccc7)cc4c65)-c4cc5ccccc5cc43)ccc21 ; Cc1cc2c(cc1N1c3cc(-c4ccccc4)cc4c3B(c3sc5cc6c(cc5c31)C(C)(C)CCC6(C)C)N(c1ccc(C(C)(C)C)cc1)c1cc3ccccc3cc1-4)C(C)(C)CCC2(C)C ; Cc1cc2c(cc1N1c3cc(-c4ccccc4)cc4c3B(c3oc5cc6c(cc5c31)C(C)(C)CCC6(C)C)N(c1ccc(C(C)(C)C)cc1)c1cc3ccccc3cc1-4)C(C)(C)CCC2(C)C] 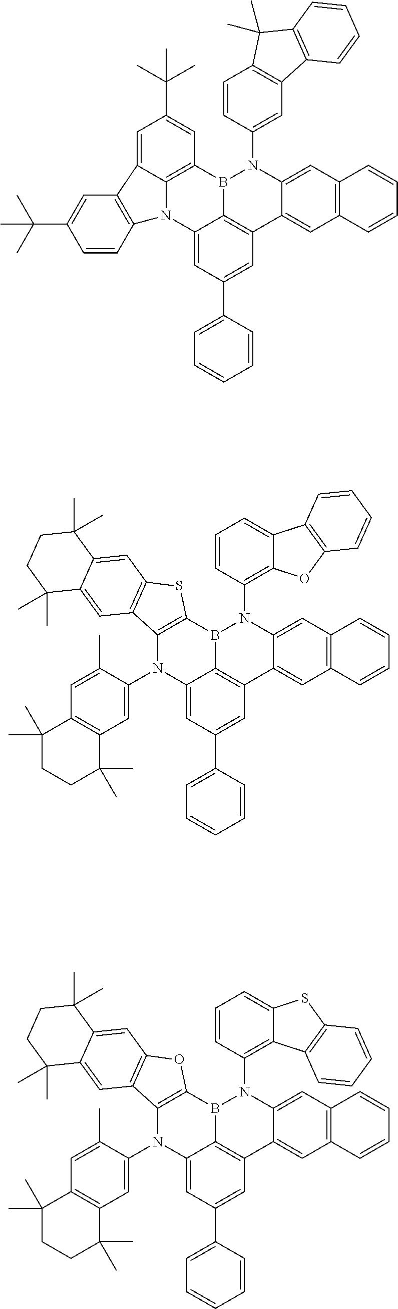 [SMILES: CC(C)(C)c1ccc2c(c1)c1cc(C(C)(C)C)cc3c1n2-c1cc(-c2ccccc2)cc2c1B3N(c1ccc3c(c1)-c1ccccc1C3(C)C)c1cc3ccccc3cc1-2 ; Cc1cc2c(cc1N1c3cc(-c4ccccc4)cc4c3B(c3sc5cc6c(cc5c31)C(C)(C)CCC6(C)C)N(c1cccc3c1oc1ccccc13)c1cc3ccccc3cc1-4)C(C)(C)CCC2(C)C ; Cc1cc2c(cc1N1c3cc(-c4ccccc4)cc4c3B(c3oc5cc6c(cc5c31)C(C)(C)CCC6(C)C)N(c1cccc3sc5ccccc5c13)c1cc3ccccc3cc1-4)C(C)(C)CCC2(C)C] 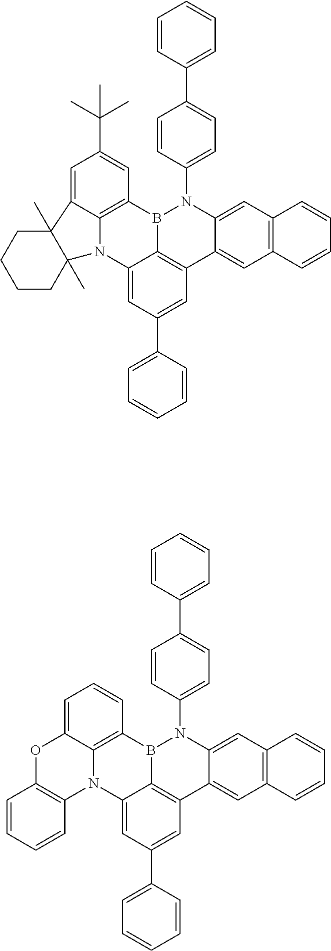 [SMILES: CC(C)(C)c1cc2c3c(c1)C1(C)CCCCC1(C)N3c1cc(-c3ccccc3)cc3c1B2N(c1ccc(-c2ccccc2)cc1)c1cc2ccccc2cc1-3 ; c1ccc(-c2ccc(N3B4c5cccc6c5N(c5ccccc5O6)c5cc(-c6ccccc6)cc(c54)-c4cc5ccccc5cc43)cc2)cc1] 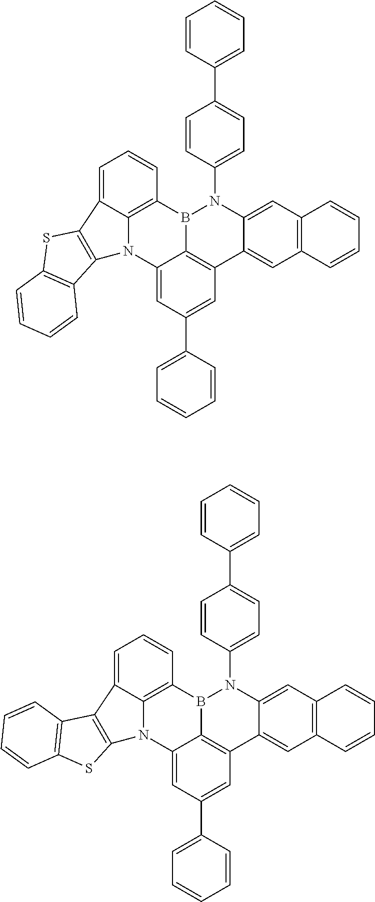 [SMILES: c1ccc(-c2ccc(N3B4c5c(cc(-c6ccccc6)cc5-n5c6c4cccc6c4sc6ccccc6c45)-c4cc5ccccc5cc43)cc2)cc1 ; c1ccc(-c2ccc(N3B4c5c(cc(-c6ccccc6)cc5-n5c6sc7ccccc7c6c6cccc4c65)-c4cc5ccccc5cc43)cc2)cc1] 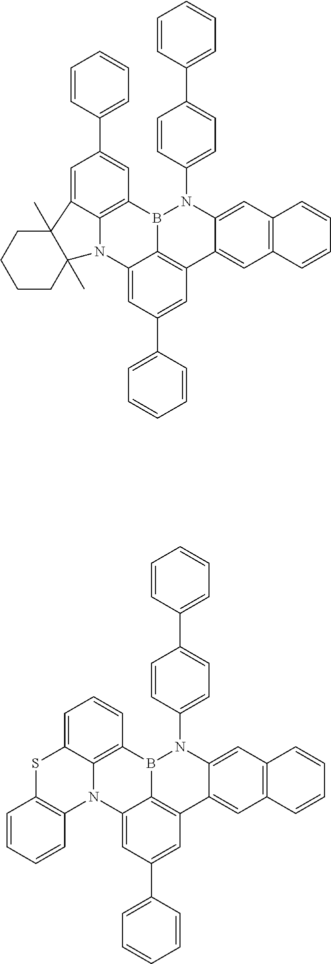 [SMILES: CC12CCCCC1(C)N1c3cc(-c4ccccc4)cc4c3B(c3cc(-c5ccccc5)cc2c31)N(c1ccc(-c2ccccc2)cc1)c1cc2ccccc2cc1-4 ; c1ccc(-c2ccc(N3B4c5cccc6c5N(c5ccccc5S6)c5cc(-c6ccccc6)cc(c54)-c4cc5ccccc5cc43)cc2)cc1] 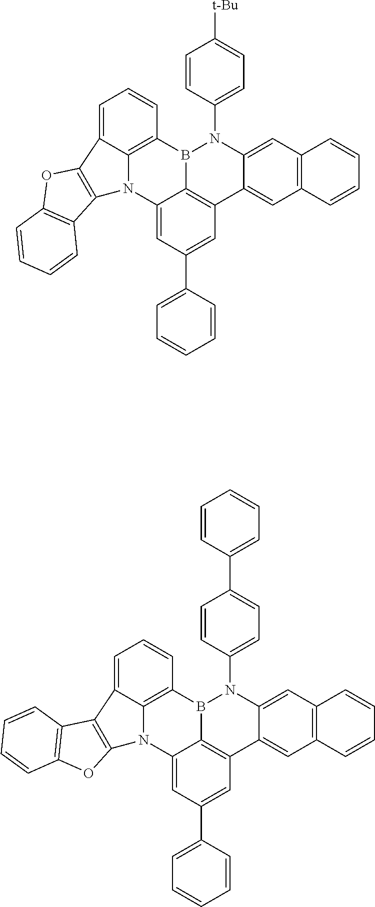 [SMILES: CC(C)(C)c1ccc(N2B3c4c(cc(-c5ccccc5)cc4-n4c5c3cccc5c3oc5ccccc5c34)-c3cc4ccccc4cc32)cc1 ; c1ccc(-c2ccc(N3B4c5c(cc(-c6ccccc6)cc5-n5c6oc7ccccc7c6c6cccc4c65)-c4cc5ccccc5cc43)cc2)cc1] 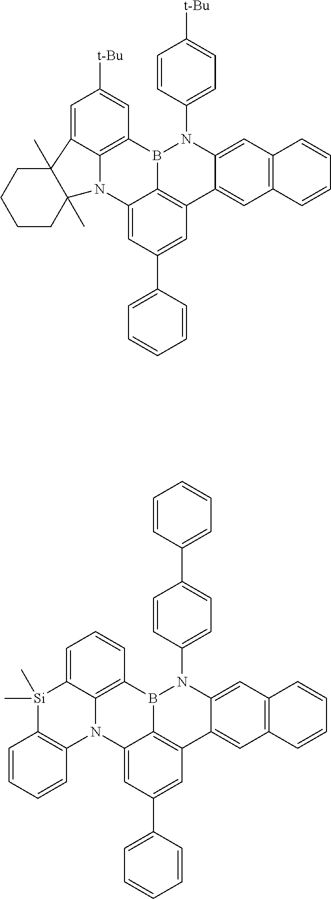 [SMILES: CC(C)(C)c1ccc(N2B3c4cc(C(C)(C)C)cc5c4N(c4cc(-c6ccccc6)cc(c43)-c3cc4ccccc4cc32)C2(C)CCCCC52C)cc1 ; C[Si]1(C)c2ccccc2N2c3cc(-c4ccccc4)cc4c3B(c3cccc1c32)N(c1ccc(-c2ccccc2)cc1)c1cc2ccccc2cc1-4] 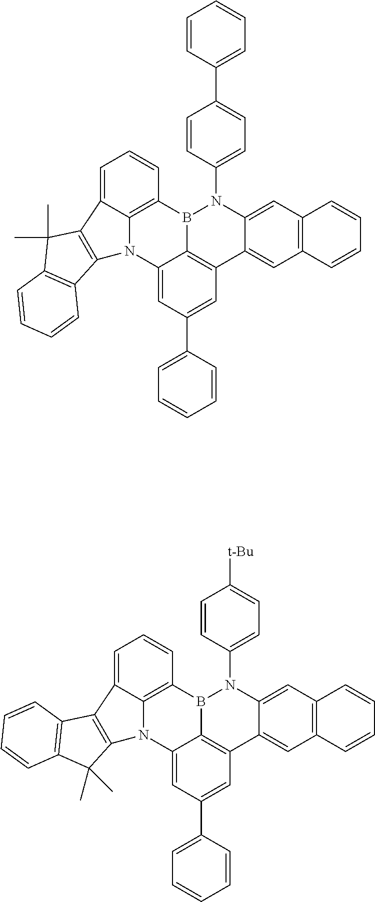 [SMILES: CC1(C)c2ccccc2-c2c1c1cccc3c1n2-c1cc(-c2ccccc2)cc2c1B3N(c1ccc(-c3ccccc3)cc1)c1cc3ccccc3cc1-2 ; CC(C)(C)c1ccc(N2B3c4c(cc(-c5ccccc5)cc4-n4c5c(c6cccc3c64)-c3ccccc3C5(C)C)-c3cc4ccccc4cc32)cc1] 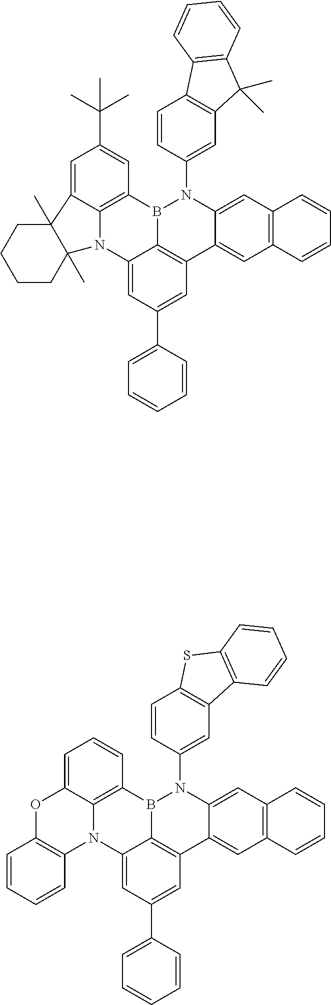 [SMILES: CC(C)(C)c1cc2c3c(c1)C1(C)CCCCC1(C)N3c1cc(-c3ccccc3)cc3c1B2N(c1ccc2c(c1)C(C)(C)c1ccccc1-2)c1cc2ccccc2cc1-3 ; c1ccc(-c2cc3c4c(c2)N2c5ccccc5Oc5cccc(c52)B4N(c2ccc4sc5ccccc5c4c2)c2cc4ccccc4cc2-3)cc1] 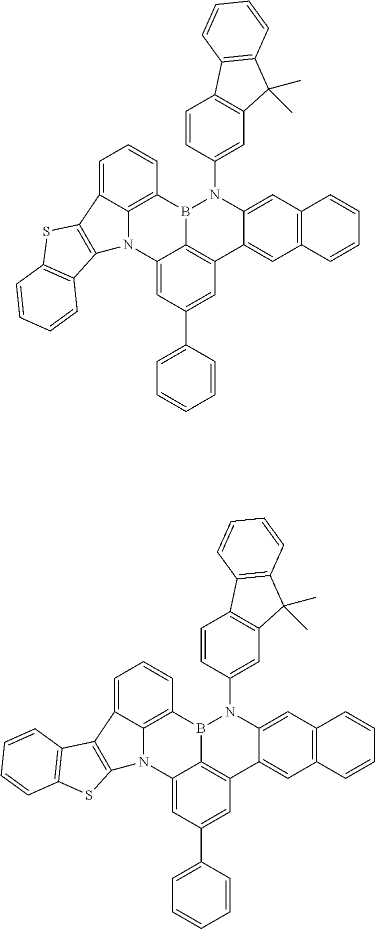 [SMILES: CC1(C)c2ccccc2-c2ccc(N3B4c5c(cc(-c6ccccc6)cc5-n5c6c4cccc6c4sc6ccccc6c45)-c4cc5ccccc5cc43)cc21 ; CC1(C)c2ccccc2-c2ccc(N3B4c5c(cc(-c6ccccc6)cc5-n5c6sc7ccccc7c6c6cccc4c65)-c4cc5ccccc5cc43)cc21] 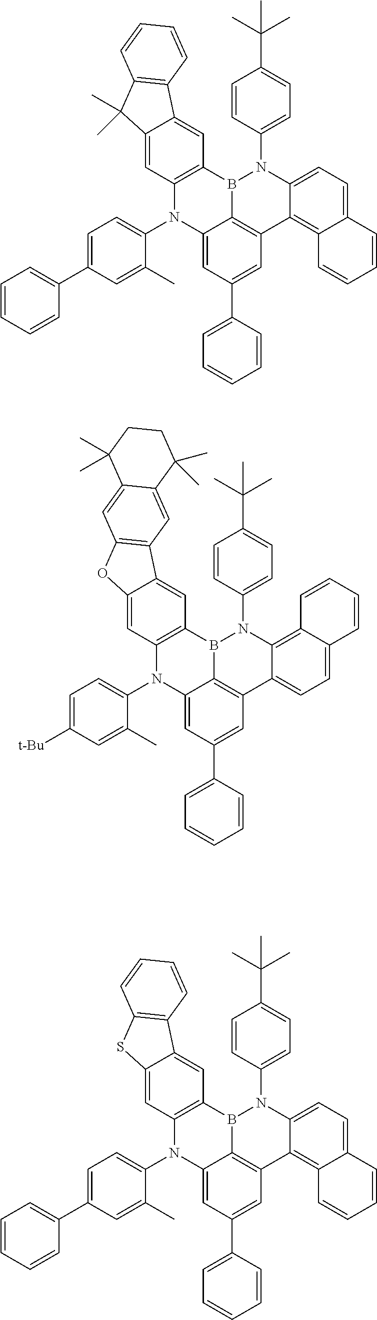 [SMILES: Cc1cc(-c2ccccc2)ccc1N1c2cc3c(cc2B2c4c(cc(-c5ccccc5)cc41)-c1c(ccc4ccccc14)N2c1ccc(C(C)(C)C)cc1)-c1ccccc1C3(C)C ; Cc1cc(C(C)(C)C)ccc1N1c2cc3oc4cc5c(cc4c3cc2B2c3c(cc(-c4ccccc4)cc31)-c1ccc3ccccc3c1N2c1ccc(C(C)(C)C)cc1)C(C)(C)CCC5(C)C ; Cc1cc(-c2ccccc2)ccc1N1c2cc3sc4ccccc4c3cc2B2c3c(cc(-c4ccccc4)cc31)-c1c(ccc3ccccc13)N2c1ccc(C(C)(C)C)cc1] 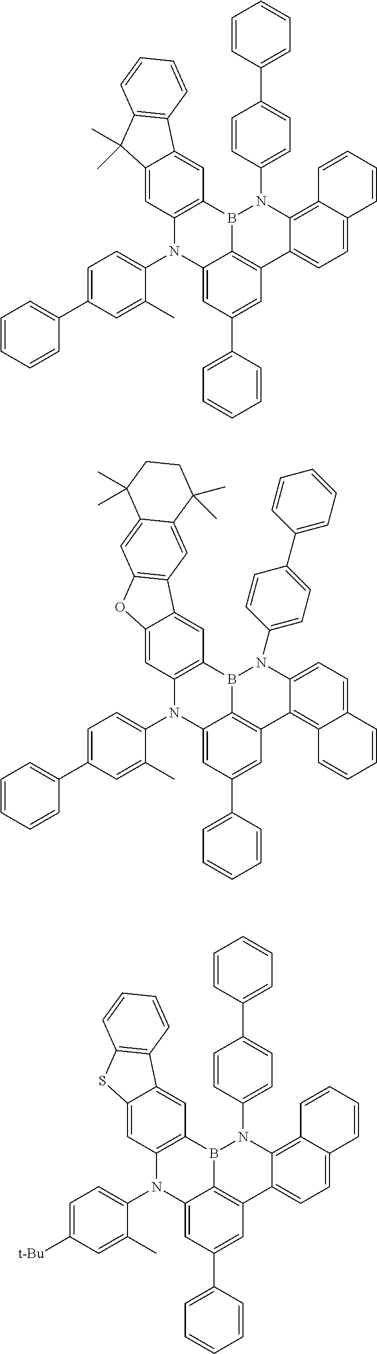 [SMILES: Cc1cc(-c2ccccc2)ccc1N1c2cc3c(cc2B2c4c(cc(-c5ccccc5)cc41)-c1ccc4ccccc4c1N2c1ccc(-c2ccccc2)cc1)-c1ccccc1C3(C)C ; Cc1cc(-c2ccccc2)ccc1N1c2cc3oc4cc5c(cc4c3cc2B2c3c(cc(-c4ccccc4)cc31)-c1c(ccc3ccccc13)N2c1ccc(-c2ccccc2)cc1)C(C)(C)CCC5(C)C ; Cc1cc(C(C)(C)C)ccc1N1c2cc3sc4ccccc4c3cc2B2c3c(cc(-c4ccccc4)cc31)-c1ccc3ccccc3c1N2c1ccc(-c2ccccc2)cc1] 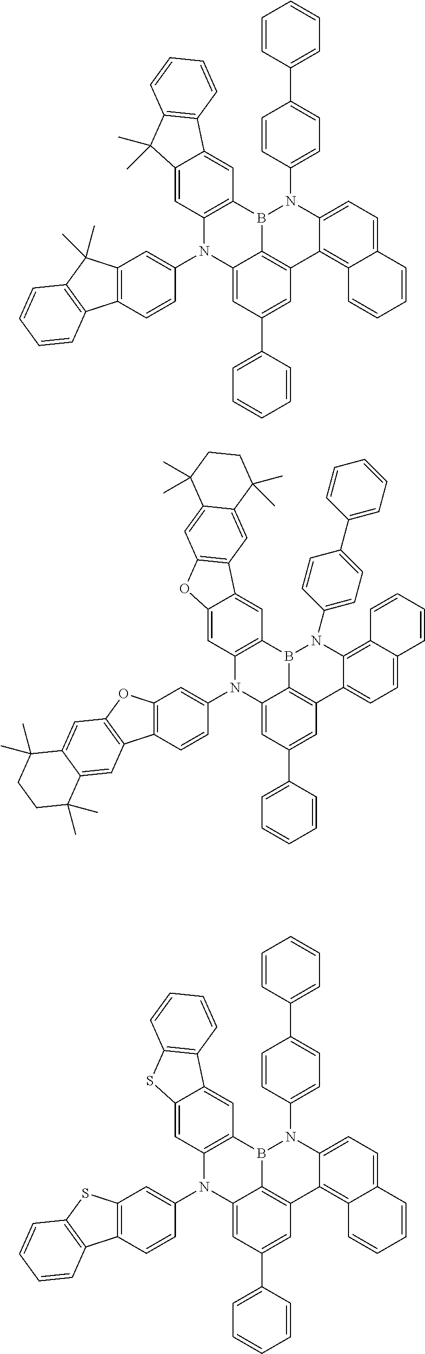 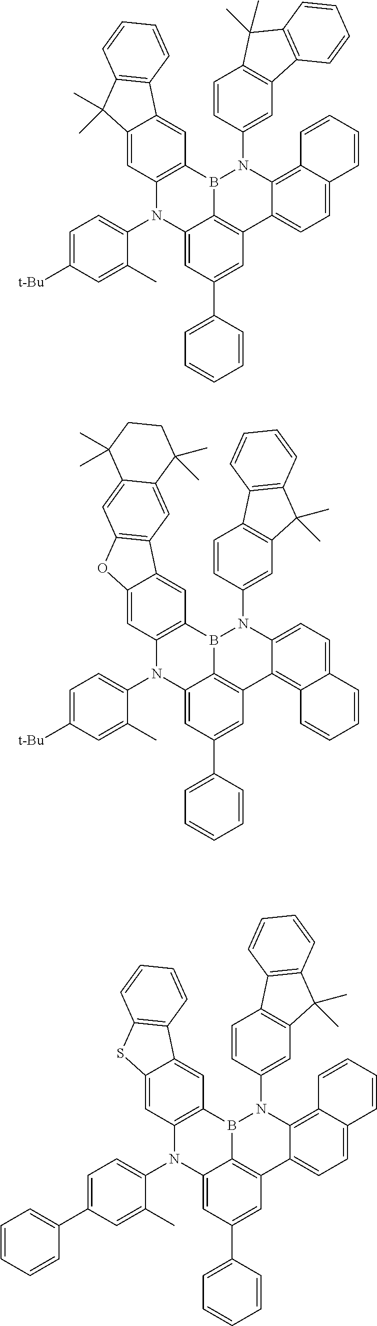 [SMILES: Cc1cc(C(C)(C)C)ccc1N1c2cc3c(cc2B2c4c(cc(-c5ccccc5)cc41)-c1ccc4ccccc4c1N2c1ccc2c(c1)-c1ccccc1C2(C)C)-c1ccccc1C3(C)C ; Cc1cc(C(C)(C)C)ccc1N1c2cc3oc4cc5c(cc4c3cc2B2c3c(cc(-c4ccccc4)cc31)-c1c(ccc3ccccc13)N2c1ccc2c(c1)C(C)(C)c1ccccc1-2)C(C)(C)CCC5(C)C ; Cc1cc(-c2ccccc2)ccc1N1c2cc3sc4ccccc4c3cc2B2c3c(cc(-c4ccccc4)cc31)-c1ccc3ccccc3c1N2c1ccc2c(c1)C(C)(C)c1ccccc1-2] 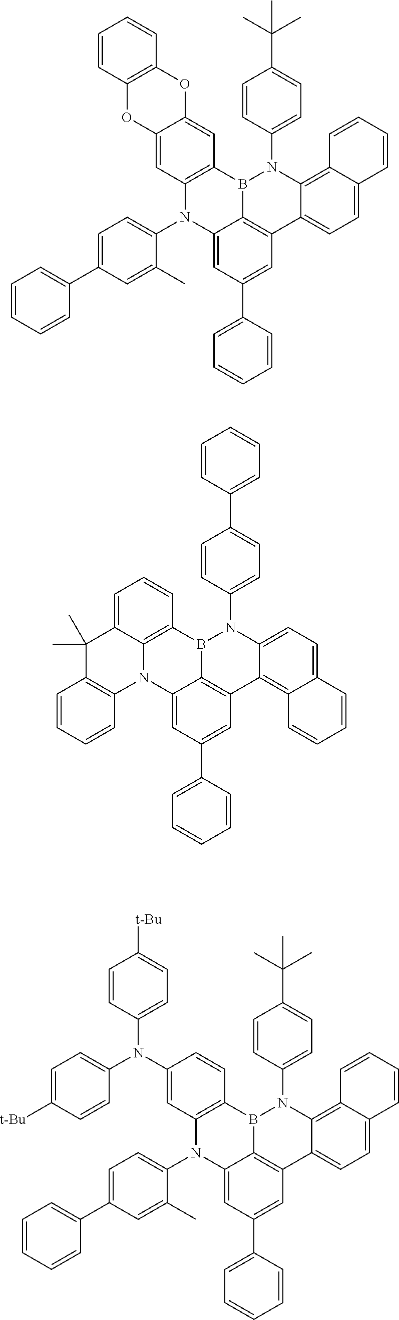 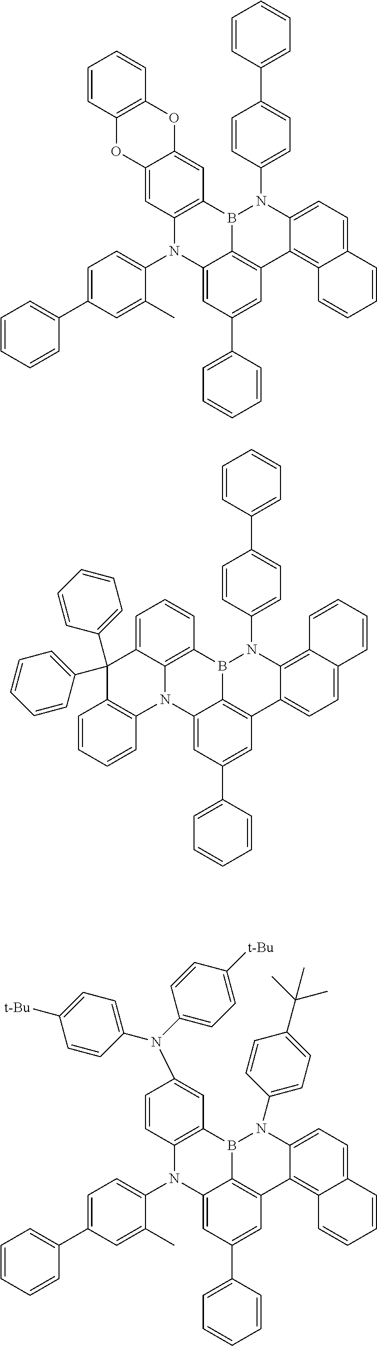 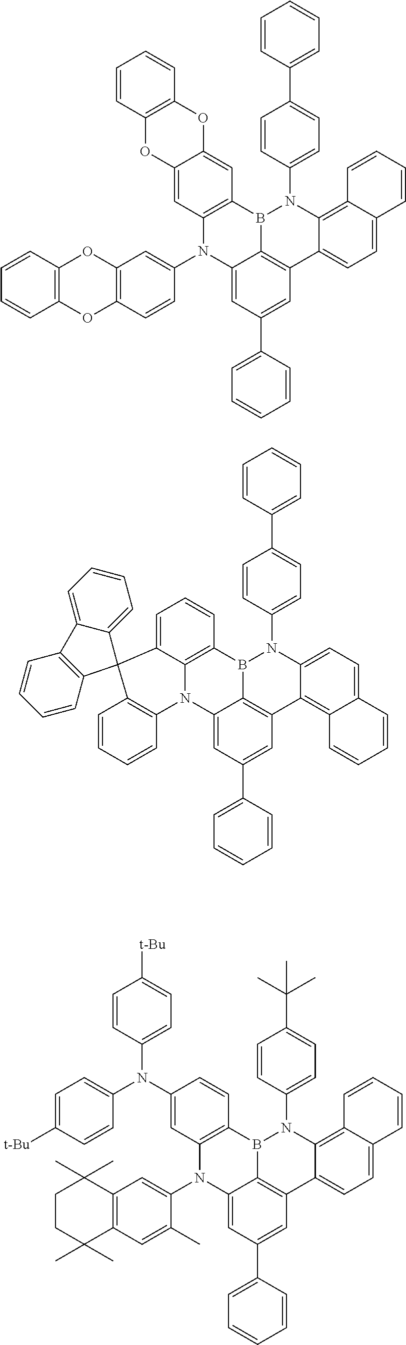 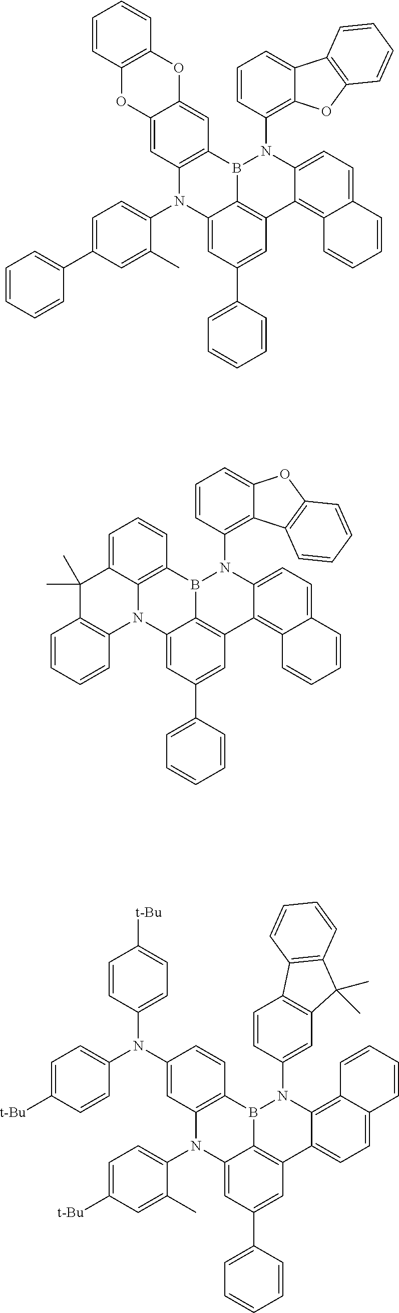 [SMILES: Cc1cc(-c2ccccc2)ccc1N1c2cc3c(cc2B2c4c(cc(-c5ccccc5)cc41)-c1c(ccc4ccccc14)N2c1cccc2c1oc1ccccc12)Oc1ccccc1O3 ; CC1(C)c2ccccc2N2c3cc(-c4ccccc4)cc4c3B(c3cccc1c32)N(c1cccc2oc3ccccc3c12)c1ccc2ccccc2c1-4 ; Cc1cc(C(C)(C)C)ccc1N1c2cc(N(c3ccc(C(C)(C)C)cc3)c3ccc(C(C)(C)C)cc3)ccc2B2c3c(cc(-c4ccccc4)cc31)-c1ccc3ccccc3c1N2c1ccc2c(c1)C(C)(C)c1ccccc1-2] 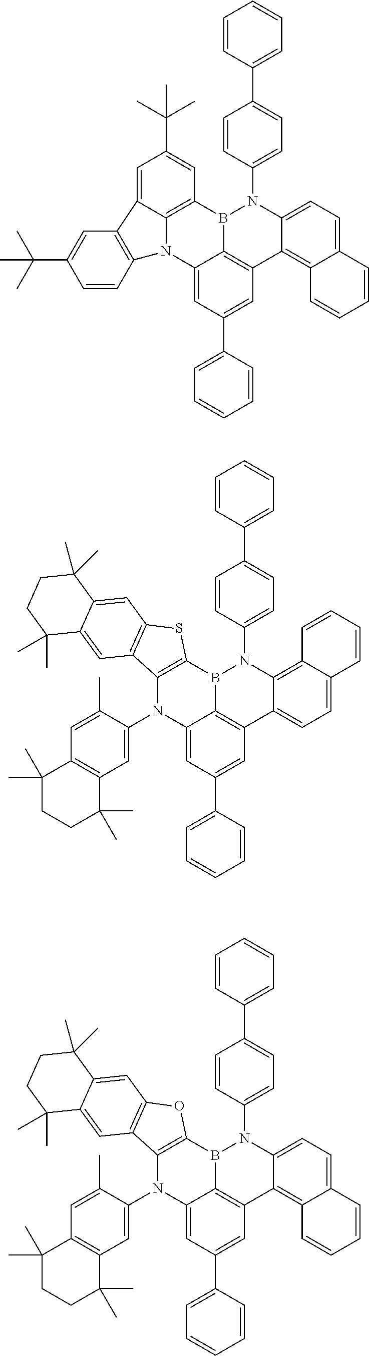 [SMILES: CC(C)(C)c1ccc2c(c1)c1cc(C(C)(C)C)cc3c1n2-c1cc(-c2ccccc2)cc2c1B3N(c1ccc(-c3ccccc3)cc1)c1ccc3ccccc3c1-2 ; Cc1cc2c(cc1N1c3cc(-c4ccccc4)cc4c3B(c3sc5cc6c(cc5c31)C(C)(C)CCC6(C)C)N(c1ccc(-c3ccccc3)cc1)c1c-4ccc3ccccc13)C(C)(C)CCC2(C)C ; Cc1cc2c(cc1N1c3cc(-c4ccccc4)cc4c3B(c3oc5cc6c(cc5c31)C(C)(C)CCC6(C)C)N(c1ccc(-c3ccccc3)cc1)c1ccc3ccccc3c1-4)C(C)(C)CCC2(C)C] 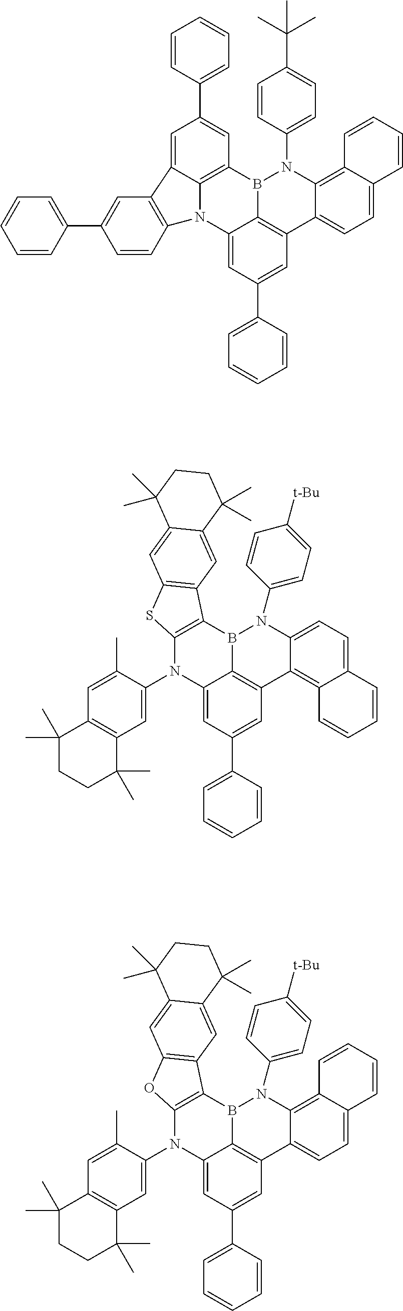 [SMILES: CC(C)(C)c1ccc(N2B3c4c(cc(-c5ccccc5)cc4-n4c5ccc(-c6ccccc6)cc5c5cc(-c6ccccc6)cc3c54)-c3ccc4ccccc4c32)cc1 ; Cc1cc2c(cc1N1c3cc(-c4ccccc4)cc4c3B(c3c1sc1cc5c(cc31)C(C)(C)CCC5(C)C)N(c1ccc(C(C)(C)C)cc1)c1ccc3ccccc3c1-4)C(C)(C)CCC2(C)C ; Cc1cc2c(cc1N1c3cc(-c4ccccc4)cc4c3B(c3c1oc1cc5c(cc31)C(C)(C)CCC5(C)C)N(c1ccc(C(C)(C)C)cc1)c1c-4ccc3ccccc13)C(C)(C)CCC2(C)C] 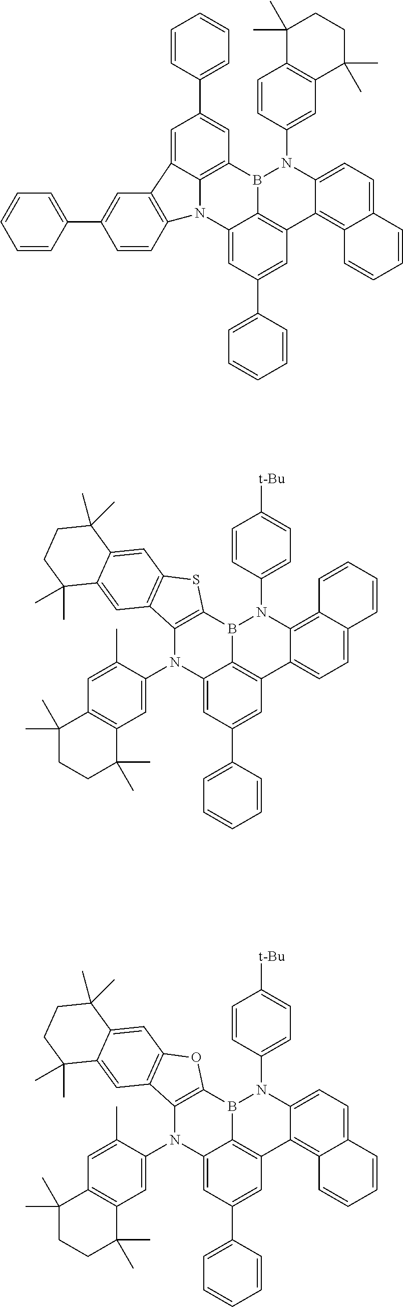 [SMILES: CC1(C)CCC(C)(C)c2cc(N3B4c5c(cc(-c6ccccc6)cc5-n5c6ccc(-c7ccccc7)cc6c6cc(-c7ccccc7)cc4c65)-c4c3ccc3ccccc43)ccc21 ; Cc1cc2c(cc1N1c3cc(-c4ccccc4)cc4c3B(c3sc5cc6c(cc5c31)C(C)(C)CCC6(C)C)N(c1ccc(C(C)(C)C)cc1)c1c-4ccc3ccccc13)C(C)(C)CCC2(C)C ; Cc1cc2c(cc1N1c3cc(-c4ccccc4)cc4c3B(c3oc5cc6c(cc5c31)C(C)(C)CCC6(C)C)N(c1ccc(C(C)(C)C)cc1)c1ccc3ccccc3c1-4)C(C)(C)CCC2(C)C] 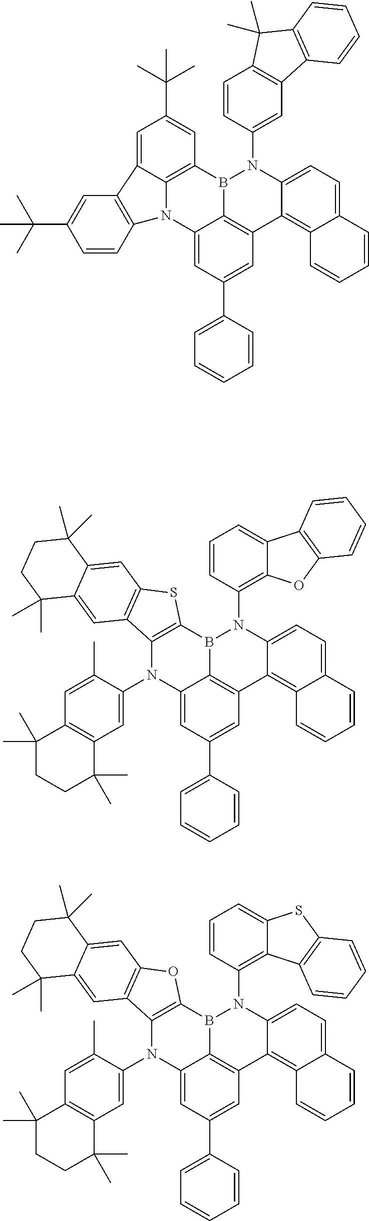 [SMILES: CC(C)(C)c1ccc2c(c1)c1cc(C(C)(C)C)cc3c1n2-c1cc(-c2ccccc2)cc2c1B3N(c1ccc3c(c1)-c1ccccc1C3(C)C)c1ccc3ccccc3c1-2 ; Cc1cc2c(cc1N1c3cc(-c4ccccc4)cc4c3B(c3sc5cc6c(cc5c31)C(C)(C)CCC6(C)C)N(c1cccc3c1oc1ccccc13)c1ccc3ccccc3c1-4)C(C)(C)CCC2(C)C ; Cc1cc2c(cc1N1c3cc(-c4ccccc4)cc4c3B(c3oc5cc6c(cc5c31)C(C)(C)CCC6(C)C)N(c1cccc3sc5ccccc5c13)c1ccc3ccccc3c1-4)C(C)(C)CCC2(C)C] 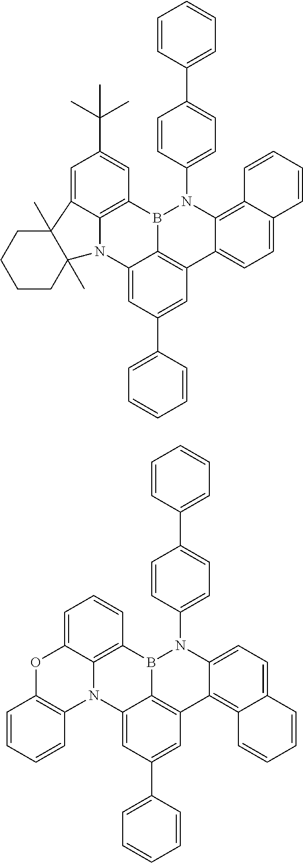 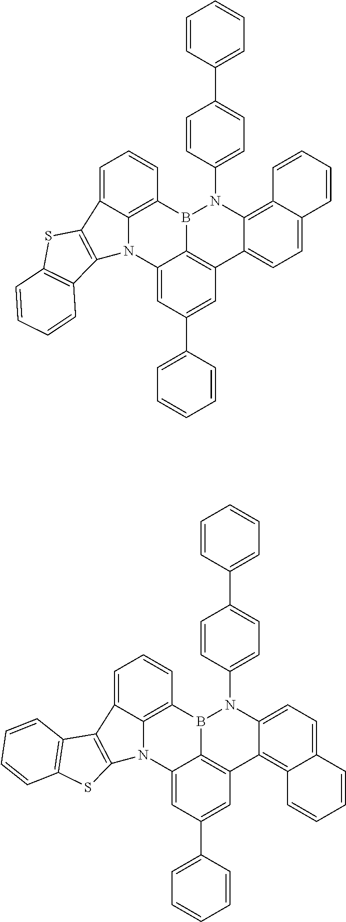 [SMILES: c1ccc(-c2ccc(N3B4c5c(cc(-c6ccccc6)cc5-n5c6c4cccc6c4sc6ccccc6c45)-c4ccc5ccccc5c43)cc2)cc1 ; c1ccc(-c2ccc(N3B4c5c(cc(-c6ccccc6)cc5-n5c6sc7ccccc7c6c6cccc4c65)-c4c3ccc3ccccc43)cc2)cc1] 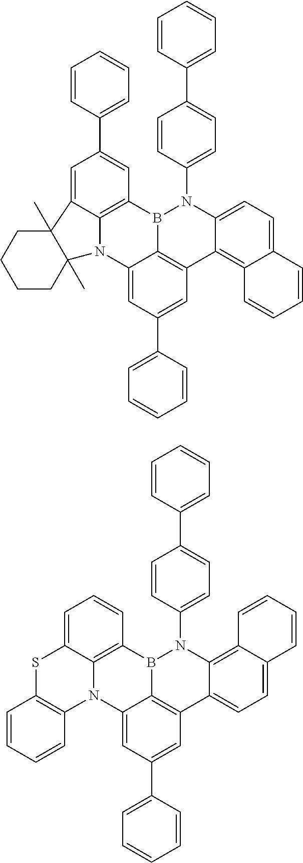 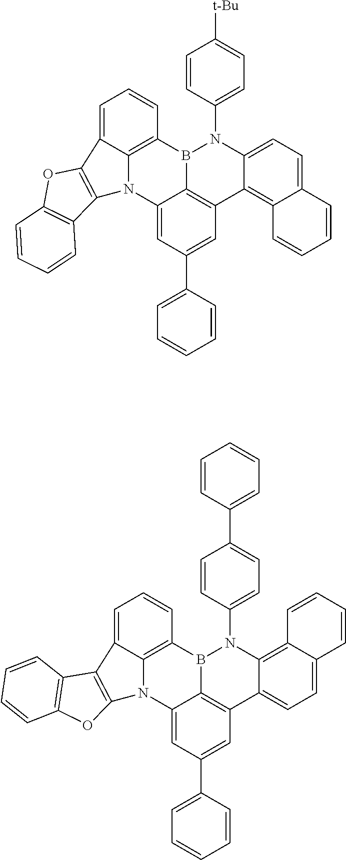 [SMILES: CC(C)(C)c1ccc(N2B3c4c(cc(-c5ccccc5)cc4-n4c5c3cccc5c3oc5ccccc5c34)-c3c2ccc2ccccc32)cc1 ; c1ccc(-c2ccc(N3B4c5c(cc(-c6ccccc6)cc5-n5c6oc7ccccc7c6c6cccc4c65)-c4ccc5ccccc5c43)cc2)cc1] 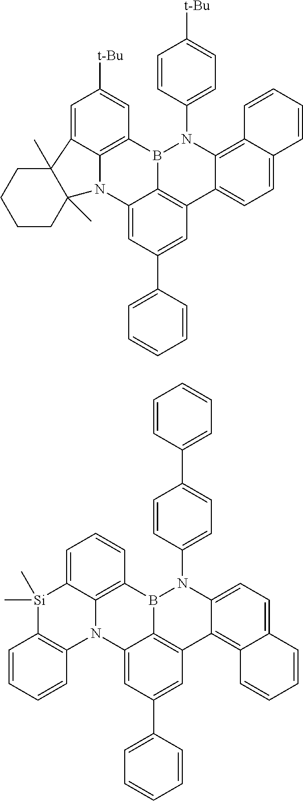 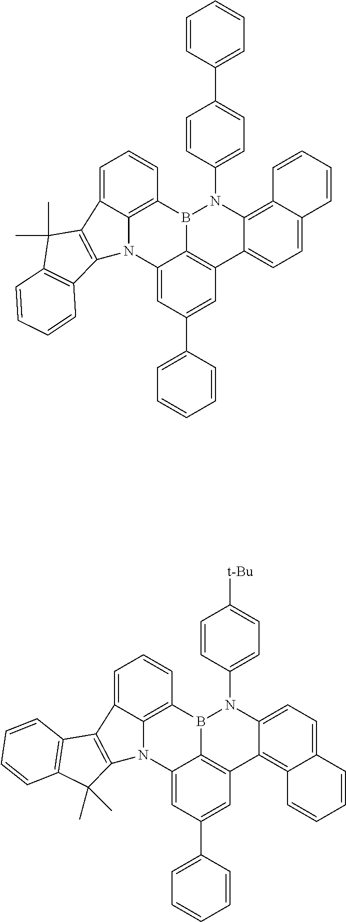 [SMILES: CC1(C)c2ccccc2-c2c1c1cccc3c1n2-c1cc(-c2ccccc2)cc2c1B3N(c1ccc(-c3ccccc3)cc1)c1c-2ccc2ccccc12 ; CC(C)(C)c1ccc(N2B3c4c(cc(-c5ccccc5)cc4-n4c5c(c6cccc3c64)-c3ccccc3C5(C)C)-c3c2ccc2ccccc32)cc1] 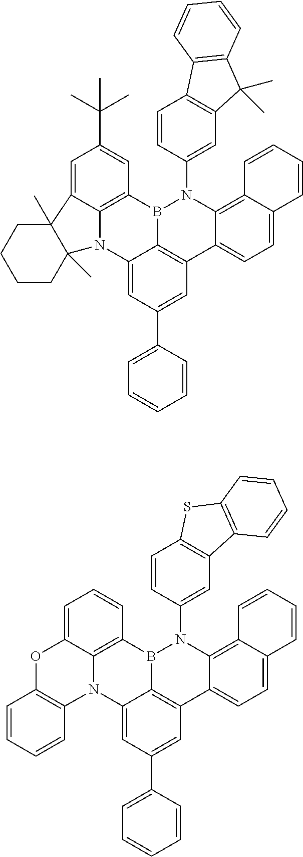 [SMILES: CC(C)(C)c1cc2c3c(c1)C1(C)CCCCC1(C)N3c1cc(-c3ccccc3)cc3c1B2N(c1ccc2c(c1)C(C)(C)c1ccccc1-2)c1c-3ccc2ccccc12 ; c1ccc(-c2cc3c4c(c2)N2c5ccccc5Oc5cccc(c52)B4N(c2ccc4sc5ccccc5c4c2)c2c-3ccc3ccccc23)cc1] 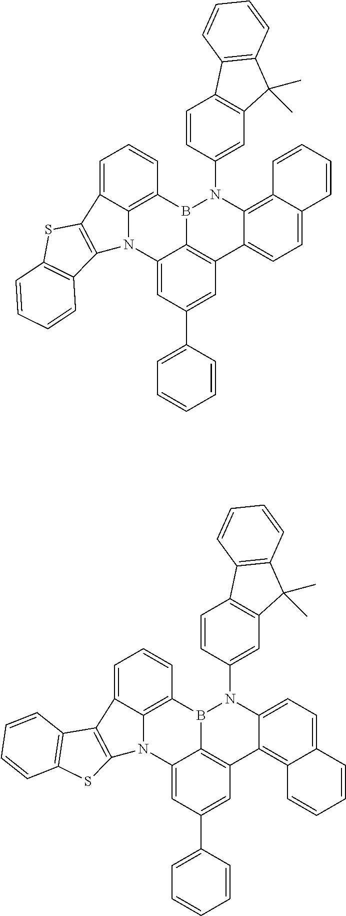 [SMILES: CC1(C)c2ccccc2-c2ccc(N3B4c5c(cc(-c6ccccc6)cc5-n5c6c4cccc6c4sc6ccccc6c45)-c4ccc5ccccc5c43)cc21 ; CC1(C)c2ccccc2-c2ccc(N3B4c5c(cc(-c6ccccc6)cc5-n5c6sc7ccccc7c6c6cccc4c65)-c4c3ccc3ccccc43)cc21] 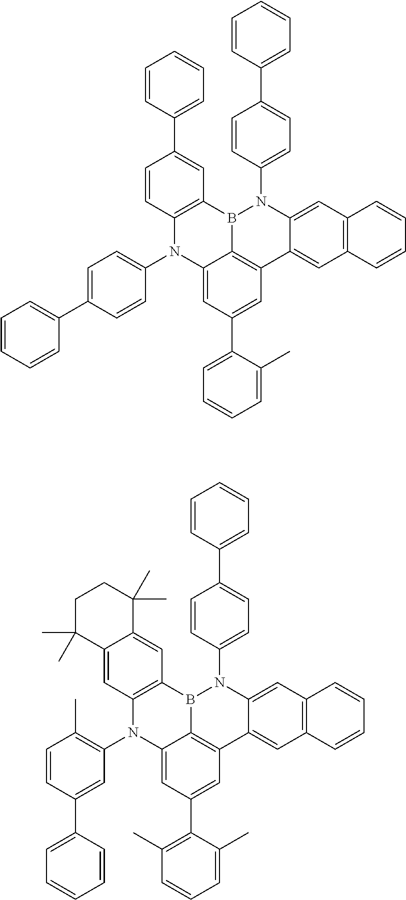 [SMILES: Cc1ccccc1-c1cc2c3c(c1)N(c1ccc(-c4ccccc4)cc1)c1ccc(-c4ccccc4)cc1B3N(c1ccc(-c3ccccc3)cc1)c1cc3ccccc3cc1-2 ; Cc1ccc(-c2ccccc2)cc1N1c2cc3c(cc2B2c4c(cc(-c5c(C)cccc5C)cc41)-c1cc4ccccc4cc1N2c1ccc(-c2ccccc2)cc1)C(C)(C)CCC3(C)C] 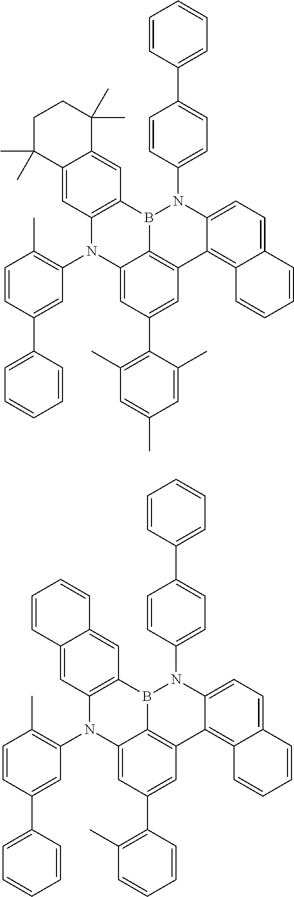 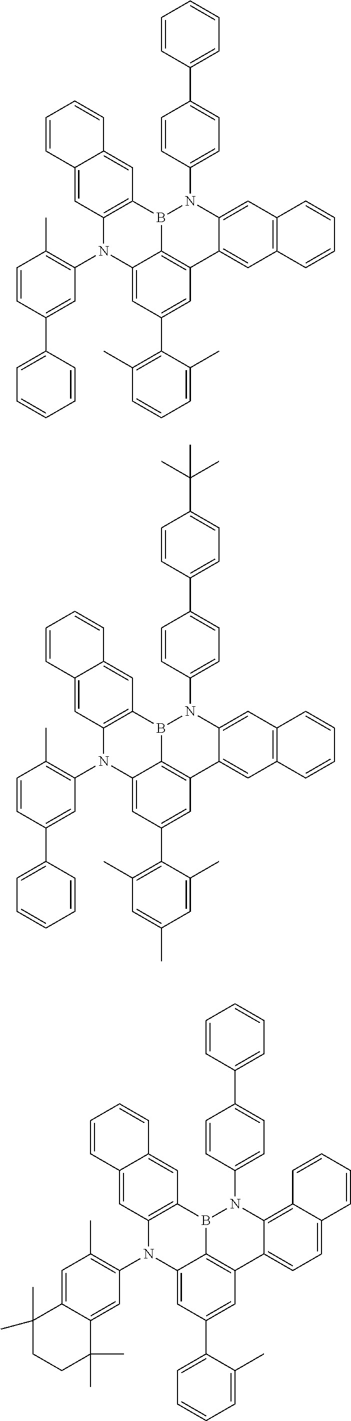 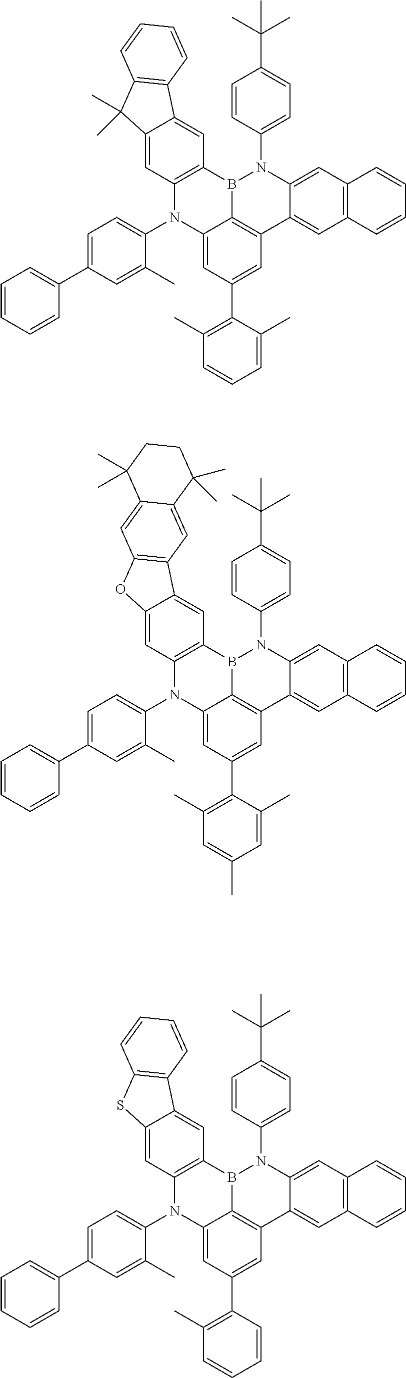 [SMILES: Cc1cc(-c2ccccc2)ccc1N1c2cc3c(cc2B2c4c(cc(-c5c(C)cccc5C)cc41)-c1cc4ccccc4cc1N2c1ccc(C(C)(C)C)cc1)-c1ccccc1C3(C)C ; Cc1cc(C)c(-c2cc3c4c(c2)N(c2ccc(-c5ccccc5)cc2C)c2cc5oc6cc7c(cc6c5cc2B4N(c2ccc(C(C)(C)C)cc2)c2cc4ccccc4cc2-3)C(C)(C)CCC7(C)C)c(C)c1 ; Cc1ccccc1-c1cc2c3c(c1)N(c1ccc(-c4ccccc4)cc1C)c1cc4sc5ccccc5c4cc1B3N(c1ccc(C(C)(C)C)cc1)c1cc3ccccc3cc1-2] 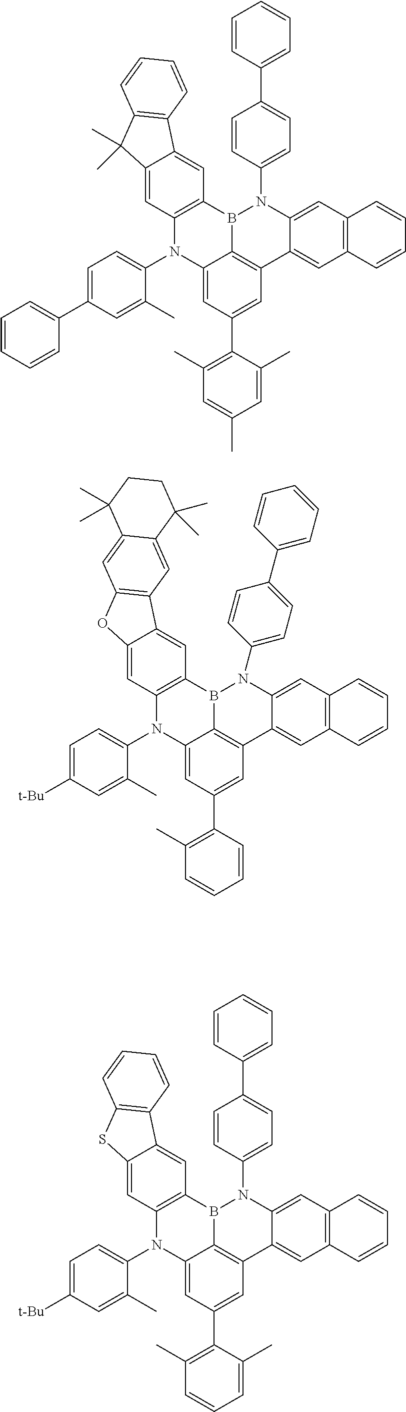 [SMILES: Cc1cc(C)c(-c2cc3c4c(c2)N(c2ccc(-c5ccccc5)cc2C)c2cc5c(cc2B4N(c2ccc(-c4ccccc4)cc2)c2cc4ccccc4cc2-3)-c2ccccc2C5(C)C)c(C)c1 ; Cc1ccccc1-c1cc2c3c(c1)N(c1ccc(C(C)(C)C)cc1C)c1cc4oc5cc6c(cc5c4cc1B3N(c1ccc(-c3ccccc3)cc1)c1cc3ccccc3cc1-2)C(C)(C)CCC6(C)C ; Cc1cc(C(C)(C)C)ccc1N1c2cc3sc4ccccc4c3cc2B2c3c(cc(-c4c(C)cccc4C)cc31)-c1cc3ccccc3cc1N2c1ccc(-c2ccccc2)cc1] 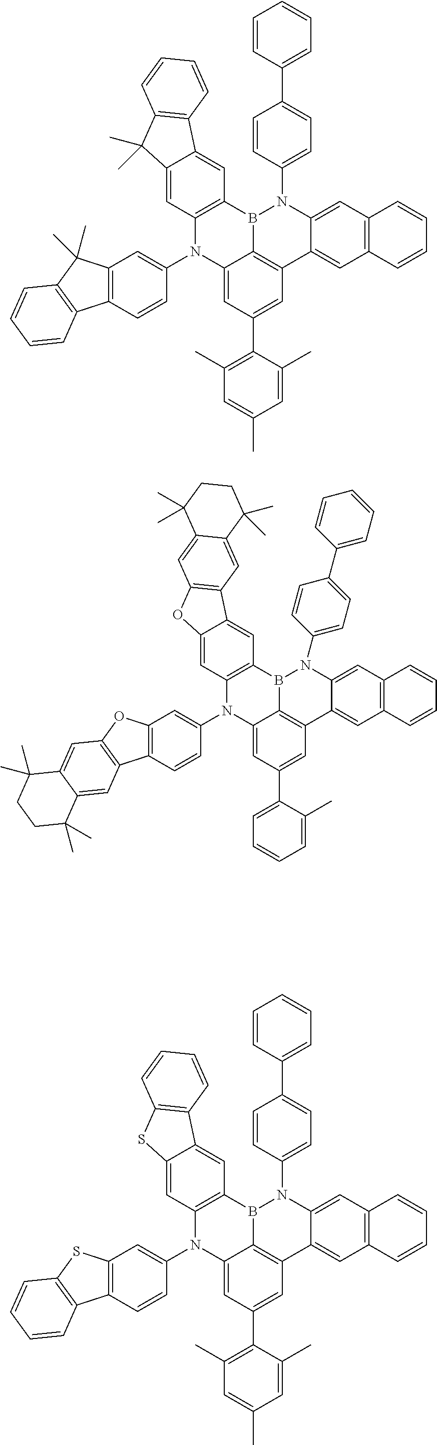 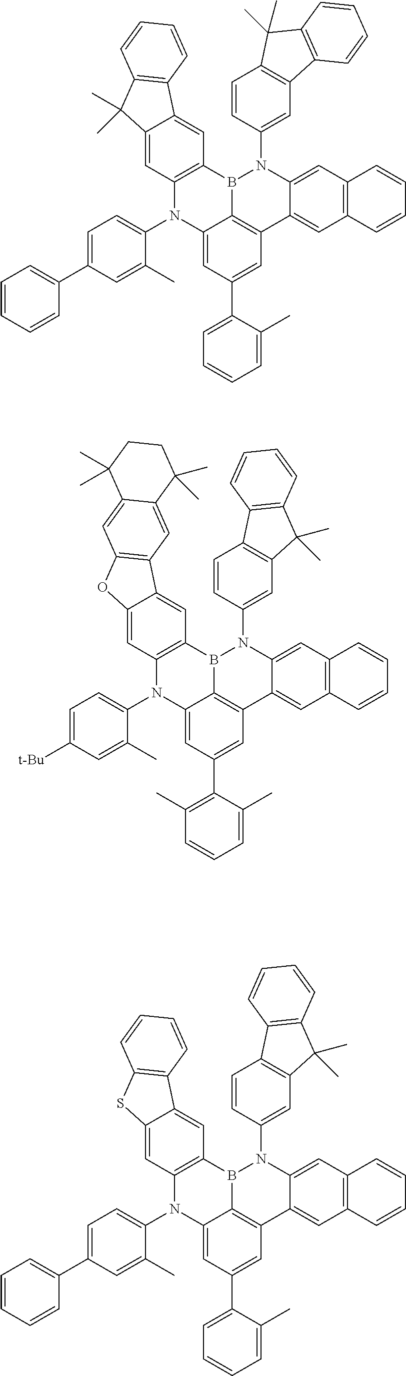 [SMILES: Cc1ccccc1-c1cc2c3c(c1)N(c1ccc(-c4ccccc4)cc1C)c1cc4c(cc1B3N(c1ccc3c(c1)-c1ccccc1C3(C)C)c1cc3ccccc3cc1-2)-c1ccccc1C4(C)C ; Cc1cc(C(C)(C)C)ccc1N1c2cc3oc4cc5c(cc4c3cc2B2c3c(cc(-c4c(C)cccc4C)cc31)-c1cc3ccccc3cc1N2c1ccc2c(c1)C(C)(C)c1ccccc1-2)C(C)(C)CCC5(C)C ; Cc1ccccc1-c1cc2c3c(c1)N(c1ccc(-c4ccccc4)cc1C)c1cc4sc5ccccc5c4cc1B3N(c1ccc3c(c1)C(C)(C)c1ccccc1-3)c1cc3ccccc3cc1-2] 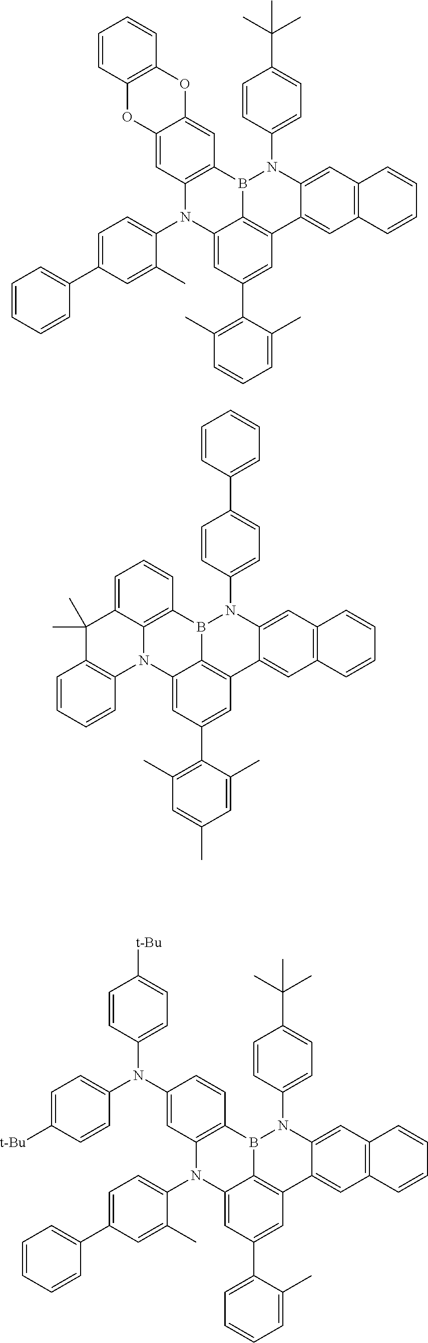 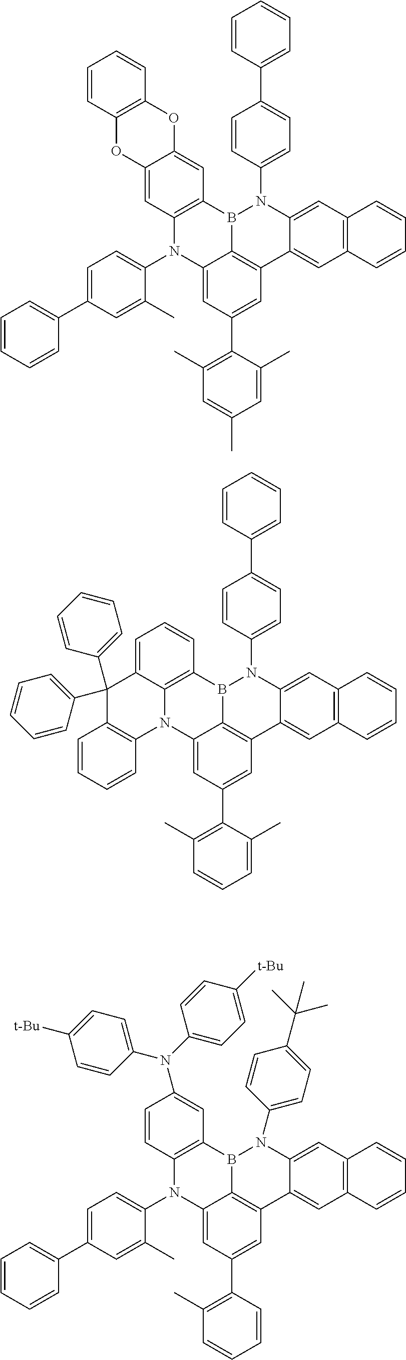 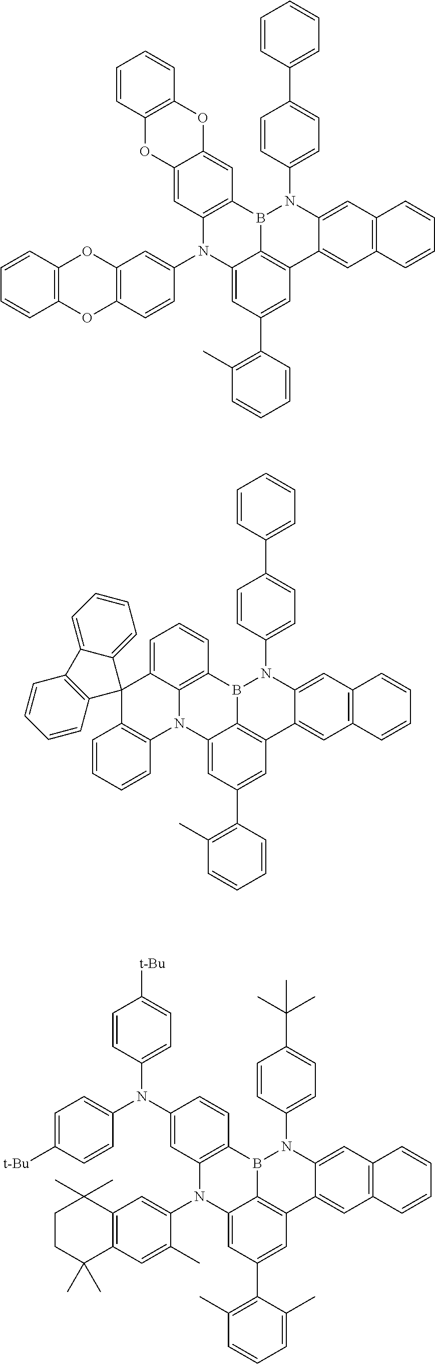 [SMILES: Cc1ccccc1-c1cc2c3c(c1)N(c1ccc4c(c1)Oc1ccccc1O4)c1cc4c(cc1B3N(c1ccc(-c3ccccc3)cc1)c1cc3ccccc3cc1-2)Oc1ccccc1O4 ; Cc1ccccc1-c1cc2c3c(c1)N1c4ccccc4C4(c5ccccc5-c5ccccc54)c4cccc(c41)B3N(c1ccc(-c3ccccc3)cc1)c1cc3ccccc3cc1-2 ; Cc1cc2c(cc1N1c3cc(N(c4ccc(C(C)(C)C)cc4)c4ccc(C(C)(C)C)cc4)ccc3B3c4c(cc(-c5c(C)cccc5C)cc41)-c1cc4ccccc4cc1N3c1ccc(C(C)(C)C)cc1)C(C)(C)CCC2(C)C] 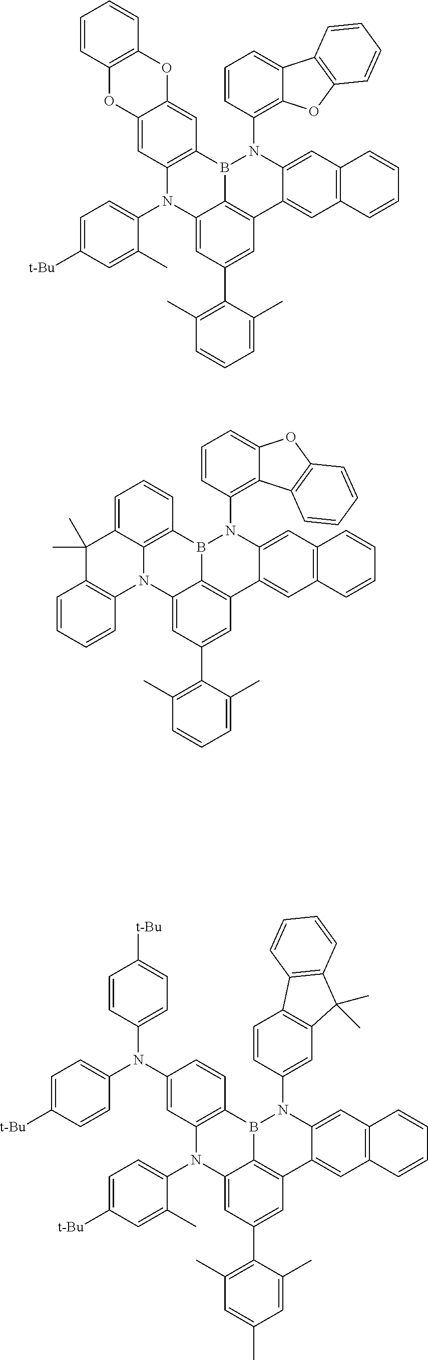 [SMILES: Cc1cc(C(C)(C)C)ccc1N1c2cc3c(cc2B2c4c(cc(-c5c(C)cccc5C)cc41)-c1cc4ccccc4cc1N2c1cccc2c1oc1ccccc12)Oc1ccccc1O3 ; Cc1cccc(C)c1-c1cc2c3c(c1)N1c4ccccc4C(C)(C)c4cccc(c41)B3N(c1cccc3oc4ccccc4c13)c1cc3ccccc3cc1-2 ; Cc1cc(C)c(-c2cc3c4c(c2)N(c2ccc(C(C)(C)C)cc2C)c2cc(N(c5ccc(C(C)(C)C)cc5)c5ccc(C(C)(C)C)cc5)ccc2B4N(c2ccc4c(c2)C(C)(C)c2ccccc2-4)c2cc4ccccc4cc2-3)c(C)c1] 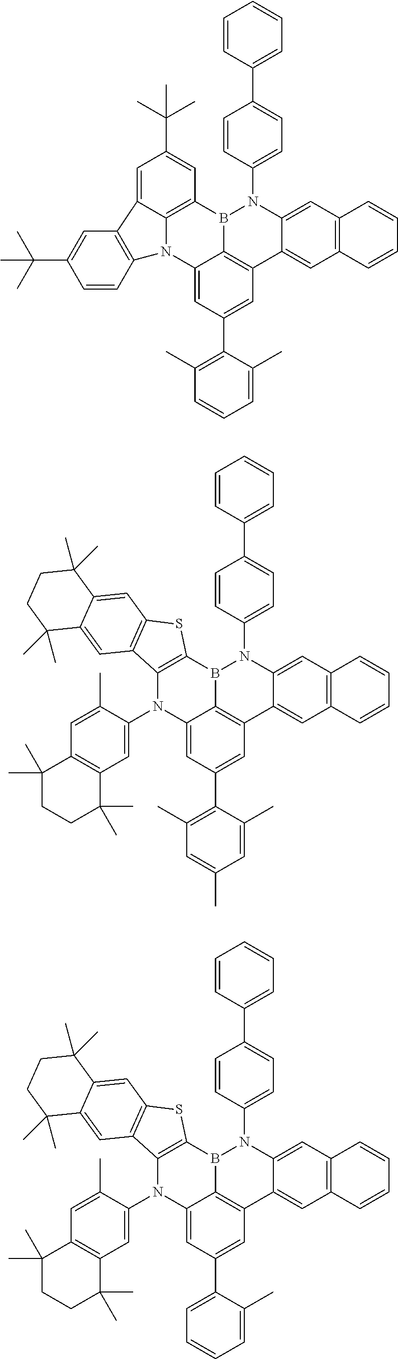 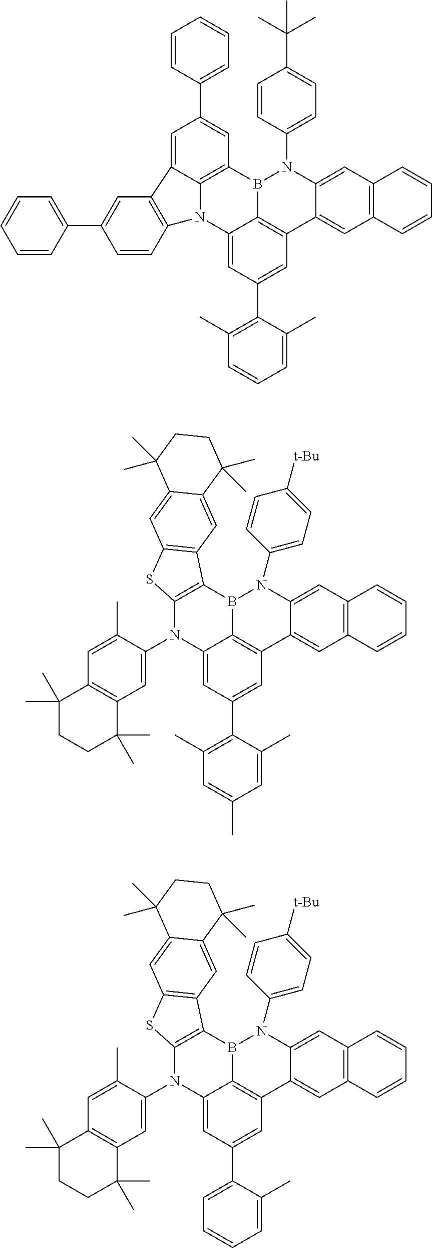 [SMILES: Cc1cccc(C)c1-c1cc2c3c(c1)-n1c4ccc(-c5ccccc5)cc4c4cc(-c5ccccc5)cc(c41)B3N(c1ccc(C(C)(C)C)cc1)c1cc3ccccc3cc1-2 ; Cc1cc(C)c(-c2cc3c4c(c2)N(c2cc5c(cc2C)C(C)(C)CCC5(C)C)c2sc5cc6c(cc5c2B4N(c2ccc(C(C)(C)C)cc2)c2cc4ccccc4cc2-3)C(C)(C)CCC6(C)C)c(C)c1 ; Cc1ccccc1-c1cc2c3c(c1)N(c1cc4c(cc1C)C(C)(C)CCC4(C)C)c1sc4cc5c(cc4c1B3N(c1ccc(C(C)(C)C)cc1)c1cc3ccccc3cc1-2)C(C)(C)CCC5(C)C] 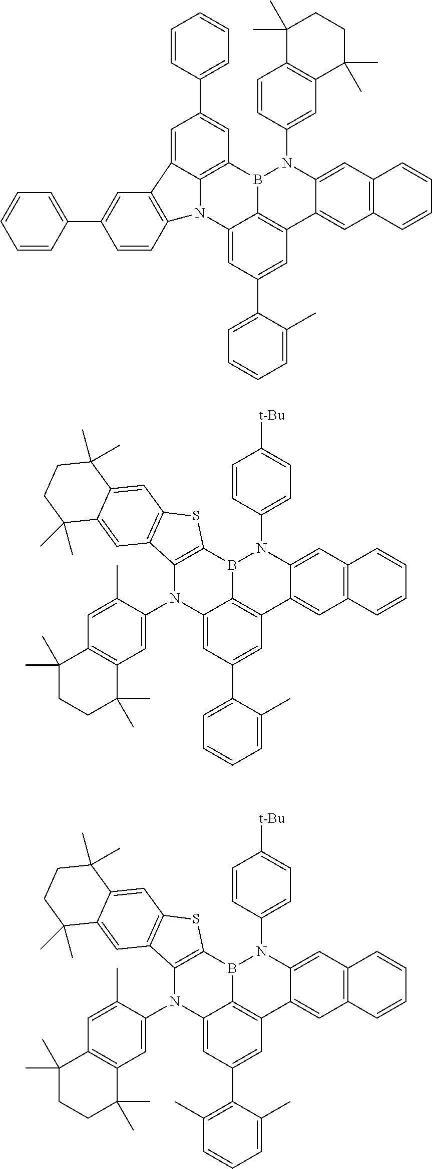 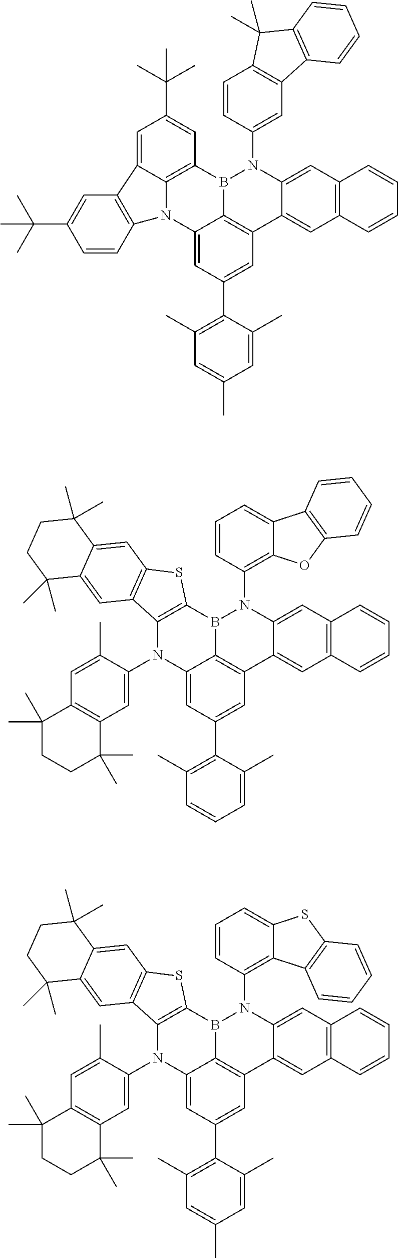 [SMILES: Cc1cc(C)c(-c2cc3c4c(c2)-n2c5ccc(C(C)(C)C)cc5c5cc(C(C)(C)C)cc(c52)B4N(c2ccc4c(c2)-c2ccccc2C4(C)C)c2cc4ccccc4cc2-3)c(C)c1 ; Cc1cc2c(cc1N1c3cc(-c4c(C)cccc4C)cc4c3B(c3sc5cc6c(cc5c31)C(C)(C)CCC6(C)C)N(c1cccc3c1oc1ccccc13)c1cc3ccccc3cc1-4)C(C)(C)CCC2(C)C ; Cc1cc(C)c(-c2cc3c4c(c2)N(c2cc5c(cc2C)C(C)(C)CCC5(C)C)c2c(sc5cc6c(cc25)C(C)(C)CCC6(C)C)B4N(c2cccc4sc5ccccc5c24)c2cc4ccccc4cc2-3)c(C)c1] 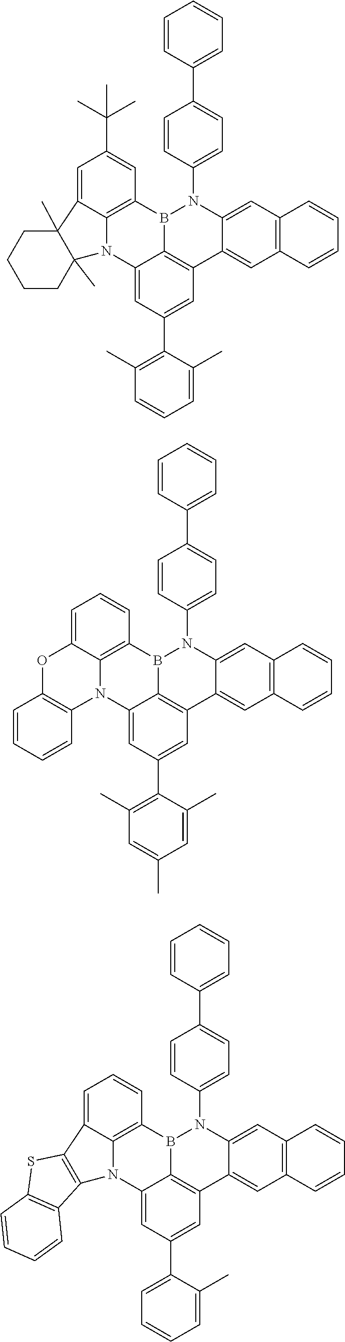 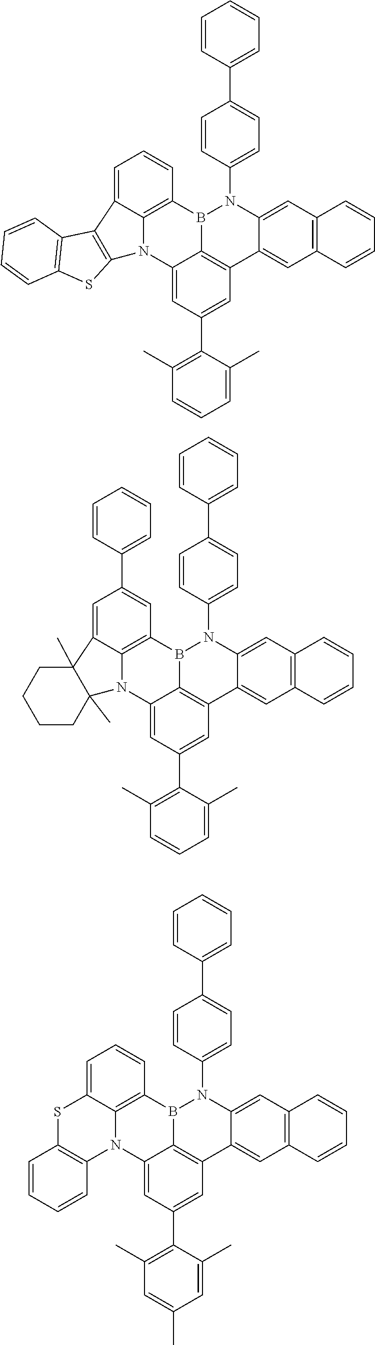 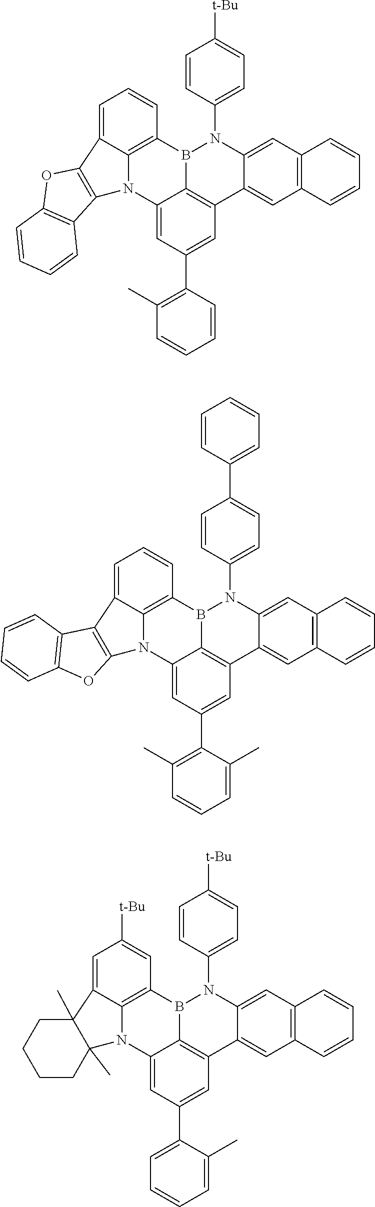 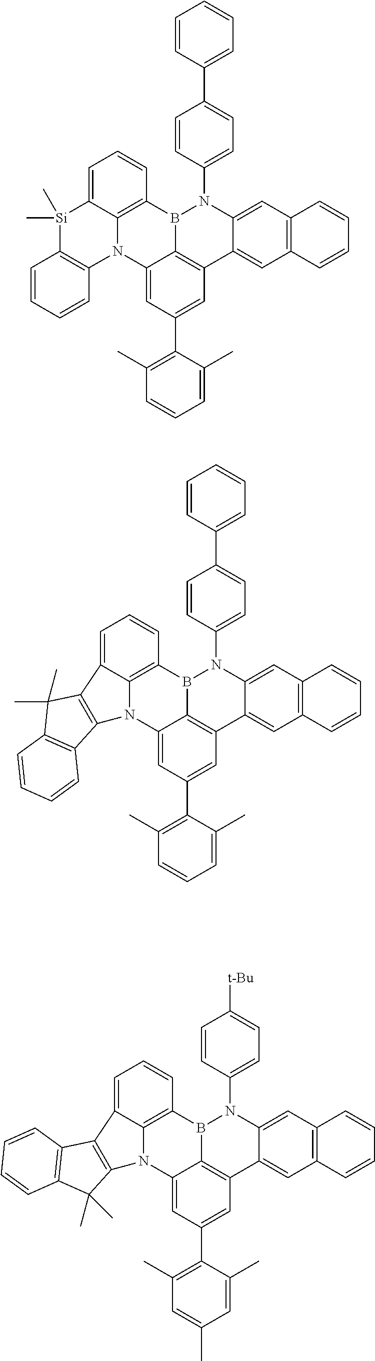 [SMILES: Cc1cccc(C)c1-c1cc2c3c(c1)N1c4ccccc4[Si](C)(C)c4cccc(c41)B3N(c1ccc(-c3ccccc3)cc1)c1cc3ccccc3cc1-2 ; Cc1cccc(C)c1-c1cc2c3c(c1)-n1c4c(c5cccc(c51)B3N(c1ccc(-c3ccccc3)cc1)c1cc3ccccc3cc1-2)C(C)(C)c1ccccc1-4 ; Cc1cc(C)c(-c2cc3c4c(c2)-n2c5c(c6cccc(c62)B4N(c2ccc(C(C)(C)C)cc2)c2cc4ccccc4cc2-3)-c2ccccc2C5(C)C)c(C)c1] 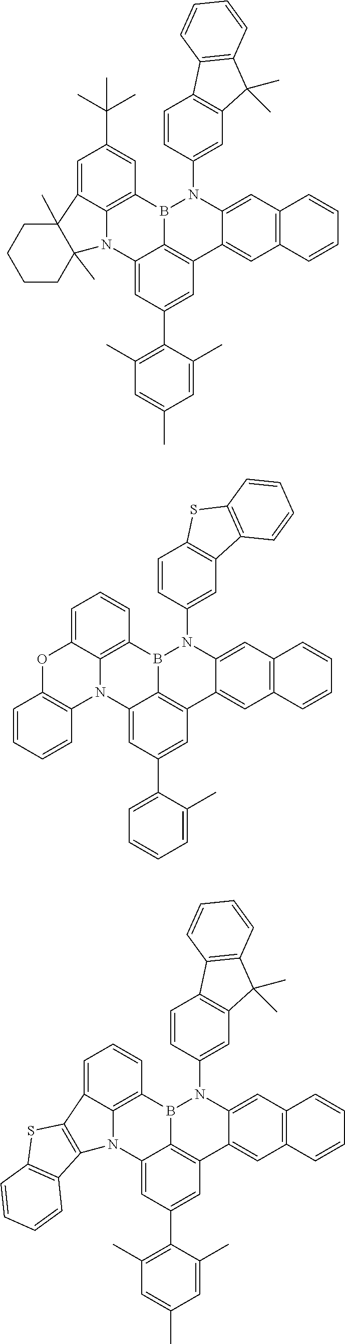 [SMILES: Cc1cc(C)c(-c2cc3c4c(c2)N2c5c(cc(C(C)(C)C)cc5C5(C)CCCCC25C)B4N(c2ccc4c(c2)C(C)(C)c2ccccc2-4)c2cc4ccccc4cc2-3)c(C)c1 ; Cc1ccccc1-c1cc2c3c(c1)N1c4ccccc4Oc4cccc(c41)B3N(c1ccc3sc4ccccc4c3c1)c1cc3ccccc3cc1-2 ; Cc1cc(C)c(-c2cc3c4c(c2)-n2c5c(cccc5c5sc6ccccc6c52)B4N(c2ccc4c(c2)C(C)(C)c2ccccc2-4)c2cc4ccccc4cc2-3)c(C)c1] 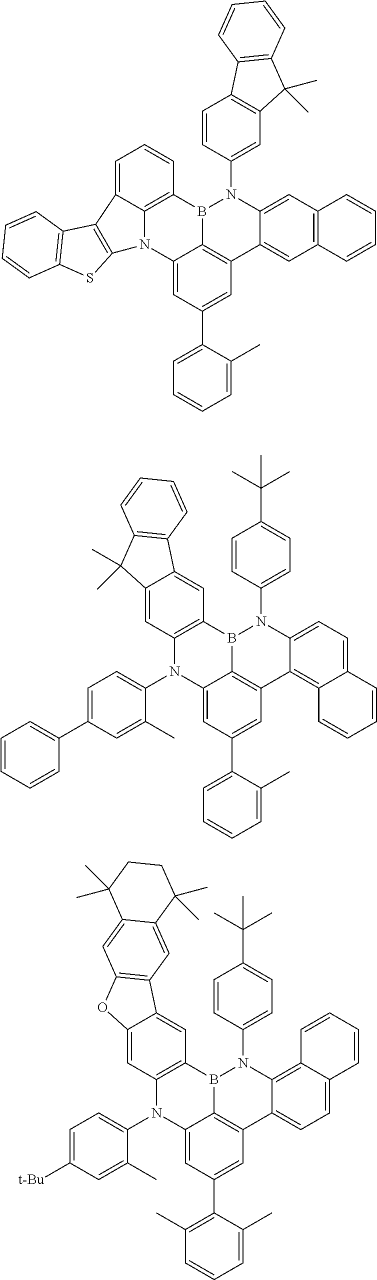 [SMILES: Cc1ccccc1-c1cc2c3c(c1)-n1c4sc5ccccc5c4c4cccc(c41)B3N(c1ccc3c(c1)C(C)(C)c1ccccc1-3)c1cc3ccccc3cc1-2 ; Cc1ccccc1-c1cc2c3c(c1)N(c1ccc(-c4ccccc4)cc1C)c1cc4c(cc1B3N(c1ccc(C(C)(C)C)cc1)c1ccc3ccccc3c1-2)-c1ccccc1C4(C)C ; Cc1cc(C(C)(C)C)ccc1N1c2cc3oc4cc5c(cc4c3cc2B2c3c(cc(-c4c(C)cccc4C)cc31)-c1ccc3ccccc3c1N2c1ccc(C(C)(C)C)cc1)C(C)(C)CCC5(C)C] 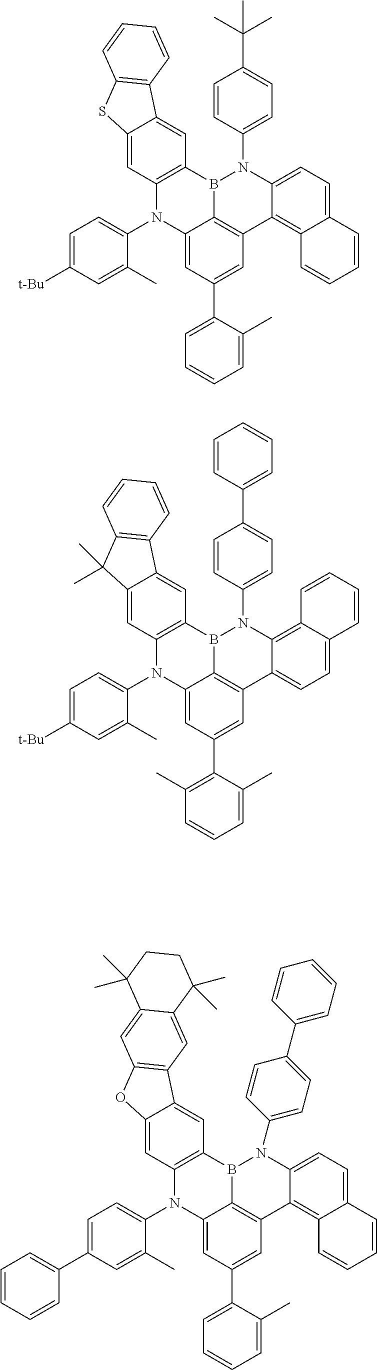 [SMILES: Cc1ccccc1-c1cc2c3c(c1)N(c1ccc(C(C)(C)C)cc1C)c1cc4sc5ccccc5c4cc1B3N(c1ccc(C(C)(C)C)cc1)c1ccc3ccccc3c1-2 ; Cc1cc(C(C)(C)C)ccc1N1c2cc3c(cc2B2c4c(cc(-c5c(C)cccc5C)cc41)-c1ccc4ccccc4c1N2c1ccc(-c2ccccc2)cc1)-c1ccccc1C3(C)C ; Cc1ccccc1-c1cc2c3c(c1)N(c1ccc(-c4ccccc4)cc1C)c1cc4oc5cc6c(cc5c4cc1B3N(c1ccc(-c3ccccc3)cc1)c1ccc3ccccc3c1-2)C(C)(C)CCC6(C)C] 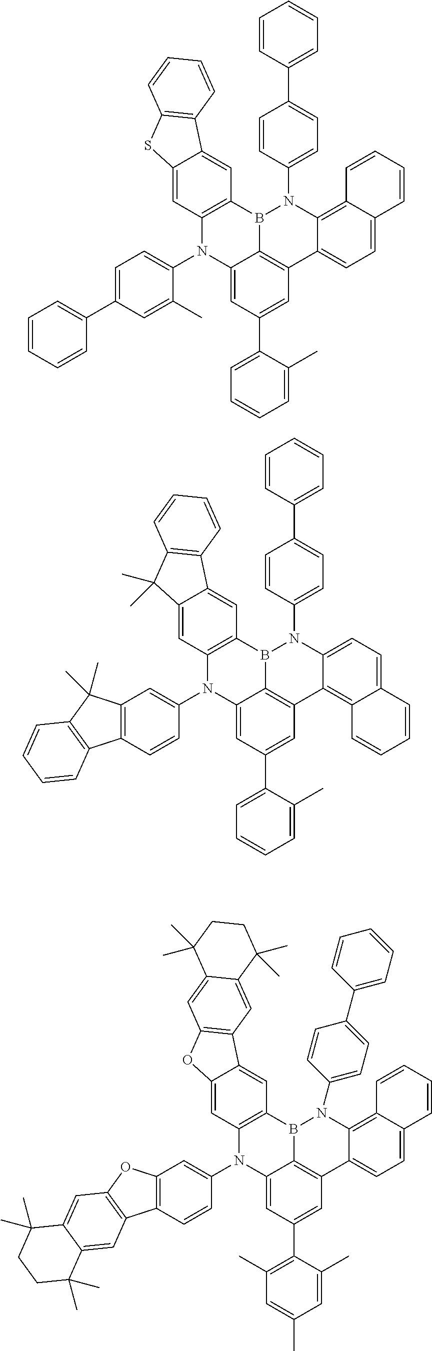 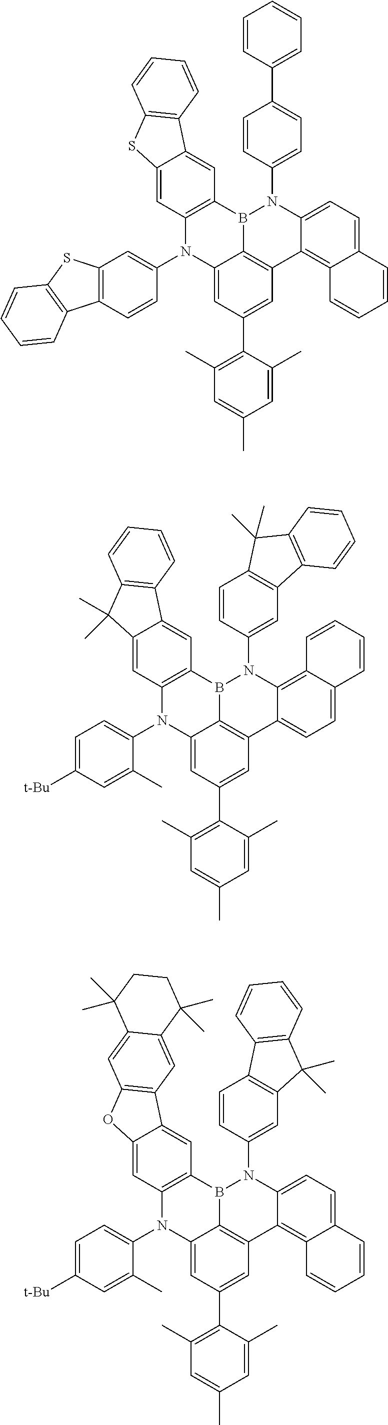 [SMILES: Cc1cc(C)c(-c2cc3c4c(c2)N(c2ccc5c(c2)sc2ccccc25)c2cc5sc6ccccc6c5cc2B4N(c2ccc(-c4ccccc4)cc2)c2ccc4ccccc4c2-3)c(C)c1 ; Cc1cc(C)c(-c2cc3c4c(c2)N(c2ccc(C(C)(C)C)cc2C)c2cc5c(cc2B4N(c2ccc4c(c2)-c2ccccc2C4(C)C)c2c-3ccc3ccccc23)-c2ccccc2C5(C)C)c(C)c1 ; Cc1cc(C)c(-c2cc3c4c(c2)N(c2ccc(C(C)(C)C)cc2C)c2cc5oc6cc7c(cc6c5cc2B4N(c2ccc4c(c2)C(C)(C)c2ccccc2-4)c2ccc4ccccc4c2-3)C(C)(C)CCC7(C)C)c(C)c1] 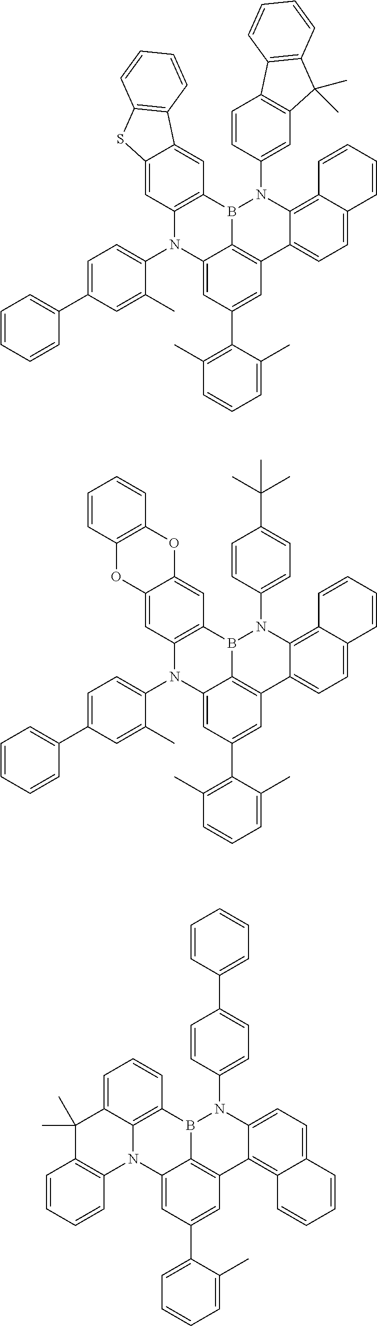 [SMILES: Cc1cc(-c2ccccc2)ccc1N1c2cc3sc4ccccc4c3cc2B2c3c(cc(-c4c(C)cccc4C)cc31)-c1ccc3ccccc3c1N2c1ccc2c(c1)C(C)(C)c1ccccc1-2 ; Cc1cc(-c2ccccc2)ccc1N1c2cc3c(cc2B2c4c(cc(-c5c(C)cccc5C)cc41)-c1ccc4ccccc4c1N2c1ccc(C(C)(C)C)cc1)Oc1ccccc1O3 ; Cc1ccccc1-c1cc2c3c(c1)N1c4ccccc4C(C)(C)c4cccc(c41)B3N(c1ccc(-c3ccccc3)cc1)c1ccc3ccccc3c1-2] 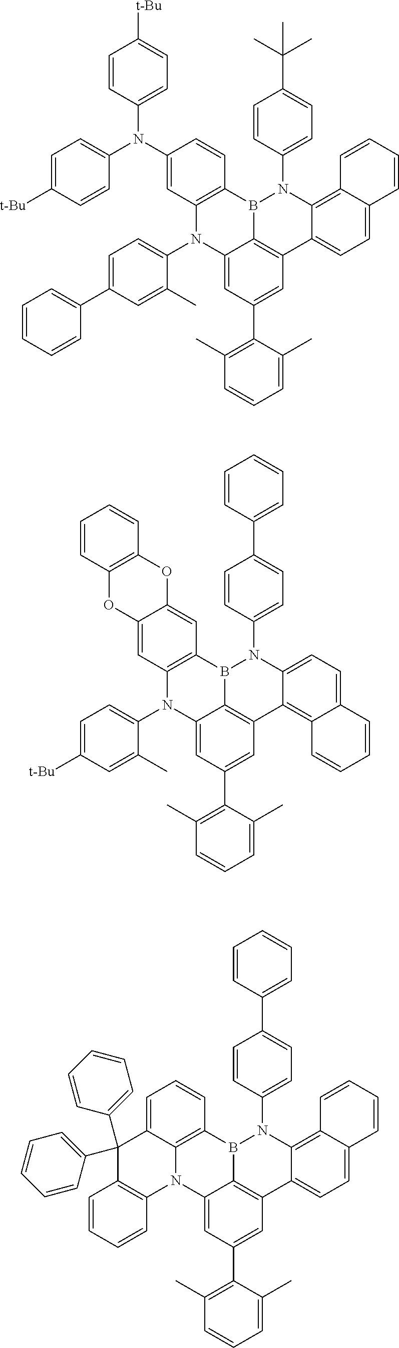 [SMILES: Cc1cc(-c2ccccc2)ccc1N1c2cc(N(c3ccc(C(C)(C)C)cc3)c3ccc(C(C)(C)C)cc3)ccc2B2c3c(cc(-c4c(C)cccc4C)cc31)-c1ccc3ccccc3c1N2c1ccc(C(C)(C)C)cc1 ; Cc1cc(C(C)(C)C)ccc1N1c2cc3c(cc2B2c4c(cc(-c5c(C)cccc5C)cc41)-c1c(ccc4ccccc14)N2c1ccc(-c2ccccc2)cc1)Oc1ccccc1O3 ; Cc1cccc(C)c1-c1cc2c3c(c1)N1c4ccccc4C(c4ccccc4)(c4ccccc4)c4cccc(c41)B3N(c1ccc(-c3ccccc3)cc1)c1c-2ccc2ccccc12] 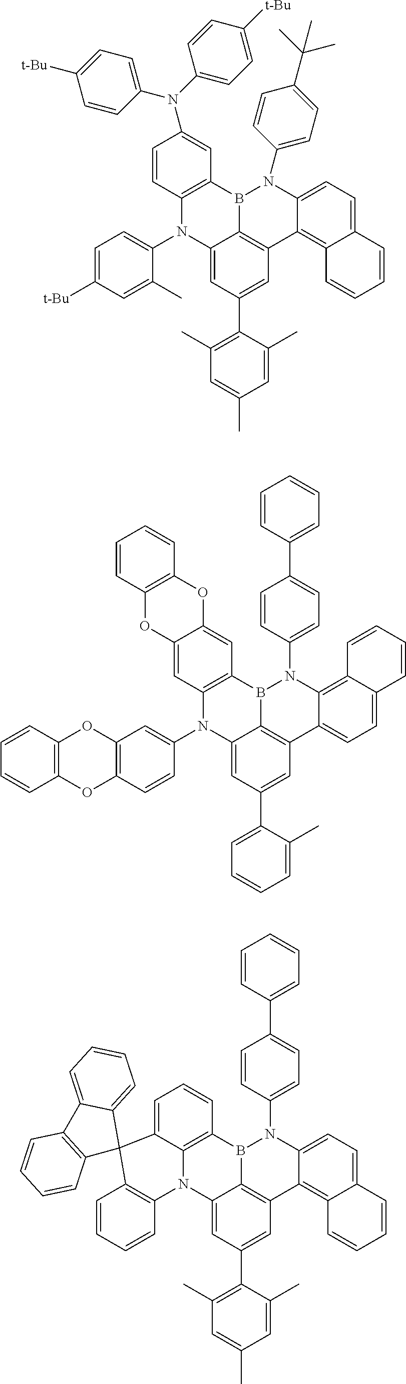 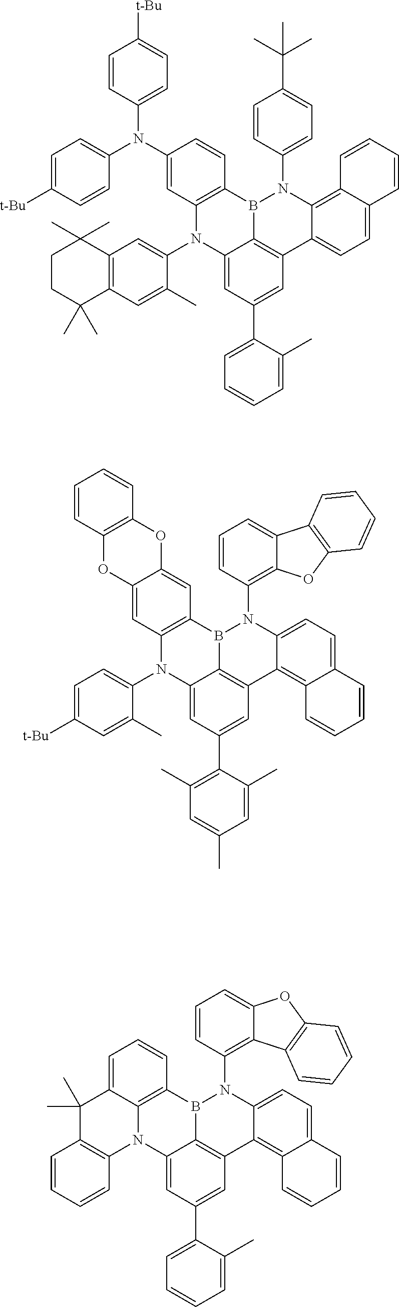 [SMILES: Cc1ccccc1-c1cc2c3c(c1)N(c1cc4c(cc1C)C(C)(C)CCC4(C)C)c1cc(N(c4ccc(C(C)(C)C)cc4)c4ccc(C(C)(C)C)cc4)ccc1B3N(c1ccc(C(C)(C)C)cc1)c1c-2ccc2ccccc12 ; Cc1cc(C)c(-c2cc3c4c(c2)N(c2ccc(C(C)(C)C)cc2C)c2cc5c(cc2B4N(c2cccc4c2oc2ccccc24)c2ccc4ccccc4c2-3)Oc2ccccc2O5)c(C)c1 ; Cc1ccccc1-c1cc2c3c(c1)N1c4ccccc4C(C)(C)c4cccc(c41)B3N(c1cccc3oc4ccccc4c13)c1ccc3ccccc3c1-2] 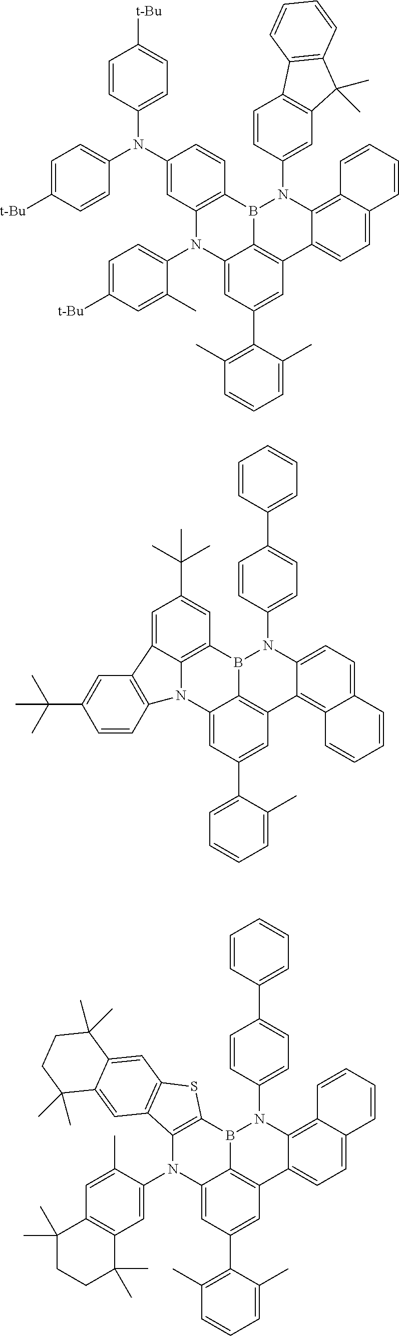 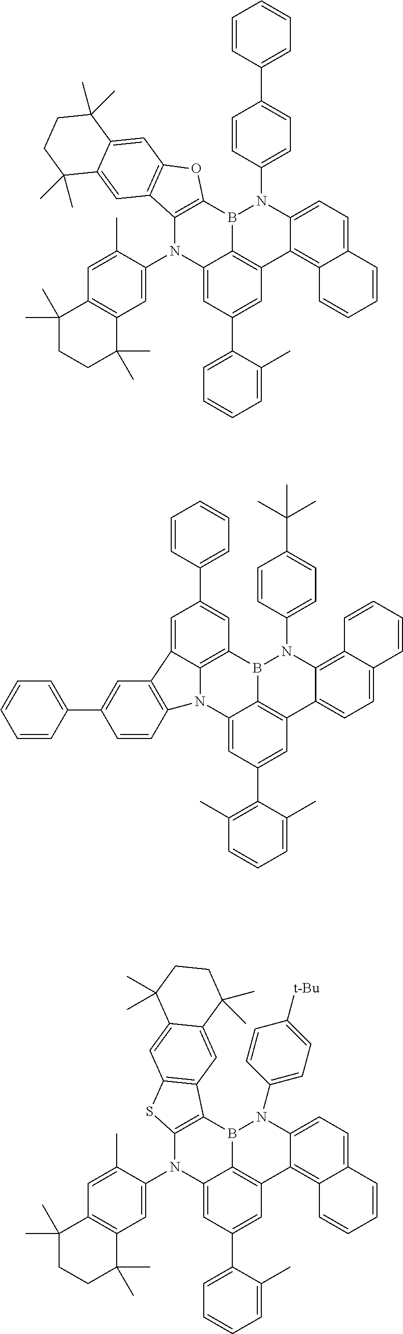 [SMILES: Cc1ccccc1-c1cc2c3c(c1)N(c1cc4c(cc1C)C(C)(C)CCC4(C)C)c1c(oc4cc5c(cc14)C(C)(C)CCC5(C)C)B3N(c1ccc(-c3ccccc3)cc1)c1ccc3ccccc3c1-2 ; Cc1cccc(C)c1-c1cc2c3c(c1)-n1c4ccc(-c5ccccc5)cc4c4cc(-c5ccccc5)cc(c41)B3N(c1ccc(C(C)(C)C)cc1)c1c-2ccc2ccccc12 ; Cc1ccccc1-c1cc2c3c(c1)N(c1cc4c(cc1C)C(C)(C)CCC4(C)C)c1sc4cc5c(cc4c1B3N(c1ccc(C(C)(C)C)cc1)c1ccc3ccccc3c1-2)C(C)(C)CCC5(C)C] 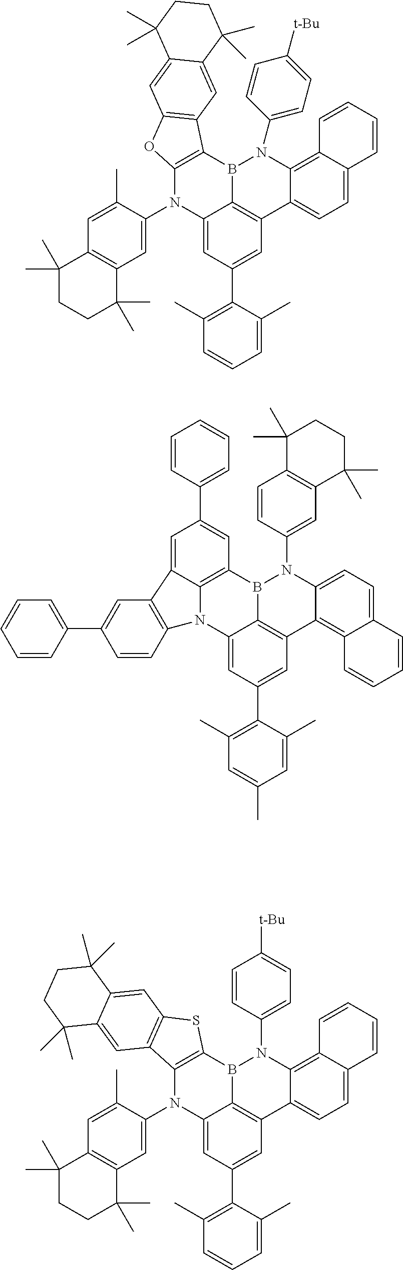 [SMILES: Cc1cc2c(cc1N1c3cc(-c4c(C)cccc4C)cc4c3B(c3c1oc1cc5c(cc31)C(C)(C)CCC5(C)C)N(c1ccc(C(C)(C)C)cc1)c1c-4ccc3ccccc13)C(C)(C)CCC2(C)C ; Cc1cc(C)c(-c2cc3c4c(c2)-n2c5ccc(-c6ccccc6)cc5c5cc(-c6ccccc6)cc(c52)B4N(c2ccc4c(c2)C(C)(C)CCC4(C)C)c2ccc4ccccc4c2-3)c(C)c1 ; Cc1cc2c(cc1N1c3cc(-c4c(C)cccc4C)cc4c3B(c3sc5cc6c(cc5c31)C(C)(C)CCC6(C)C)N(c1ccc(C(C)(C)C)cc1)c1c-4ccc3ccccc13)C(C)(C)CCC2(C)C] 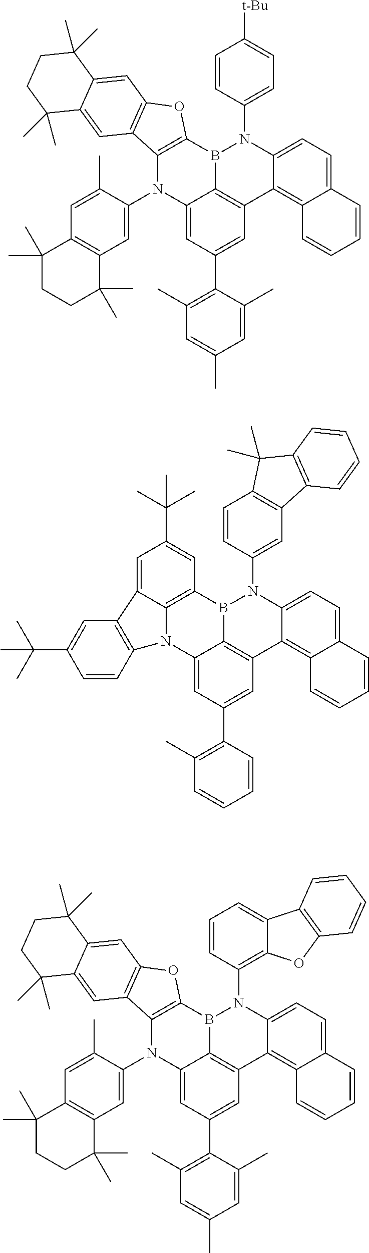 [SMILES: Cc1cc(C)c(-c2cc3c4c(c2)N(c2cc5c(cc2C)C(C)(C)CCC5(C)C)c2c(oc5cc6c(cc25)C(C)(C)CCC6(C)C)B4N(c2ccc(C(C)(C)C)cc2)c2ccc4ccccc4c2-3)c(C)c1 ; Cc1ccccc1-c1cc2c3c(c1)-n1c4ccc(C(C)(C)C)cc4c4cc(C(C)(C)C)cc(c41)B3N(c1ccc3c(c1)-c1ccccc1C3(C)C)c1ccc3ccccc3c1-2 ; Cc1cc(C)c(-c2cc3c4c(c2)N(c2cc5c(cc2C)C(C)(C)CCC5(C)C)c2c(oc5cc6c(cc25)C(C)(C)CCC6(C)C)B4N(c2cccc4c2oc2ccccc24)c2ccc4ccccc4c2-3)c(C)c1] 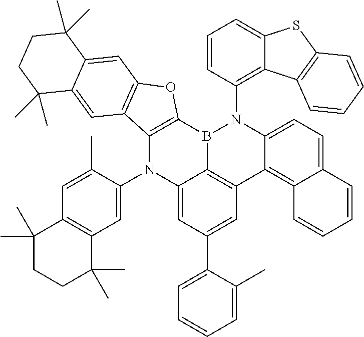 [SMILES: Cc1ccccc1-c1cc2c3c(c1)N(c1cc4c(cc1C)C(C)(C)CCC4(C)C)c1c(oc4cc5c(cc14)C(C)(C)CCC5(C)C)B3N(c1cccc3sc4ccccc4c13)c1ccc3ccccc3c1-2] 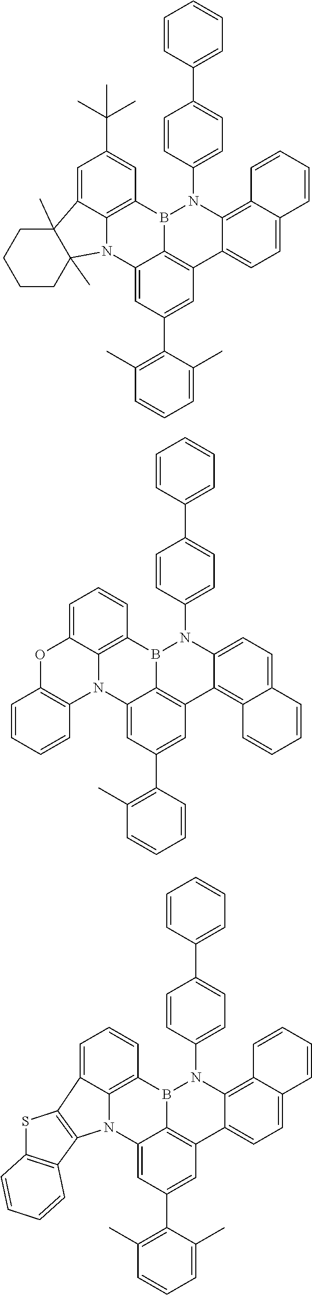 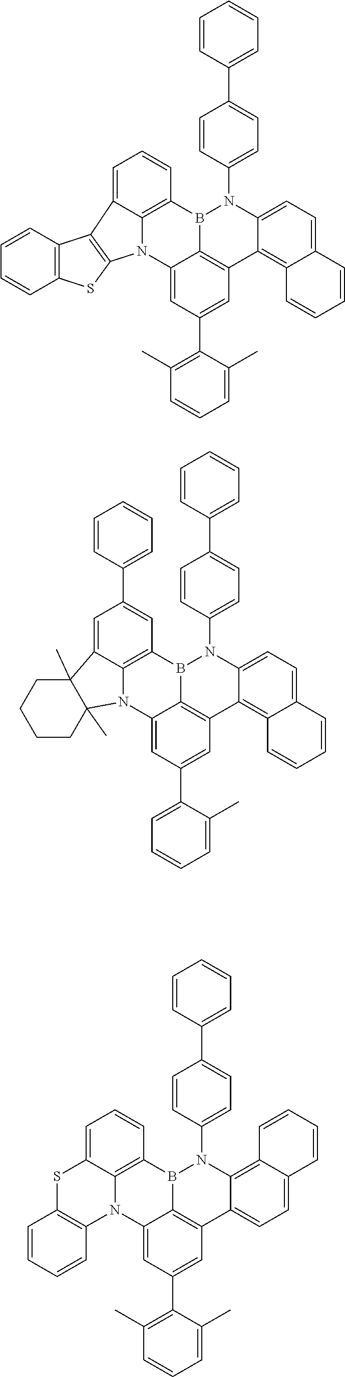 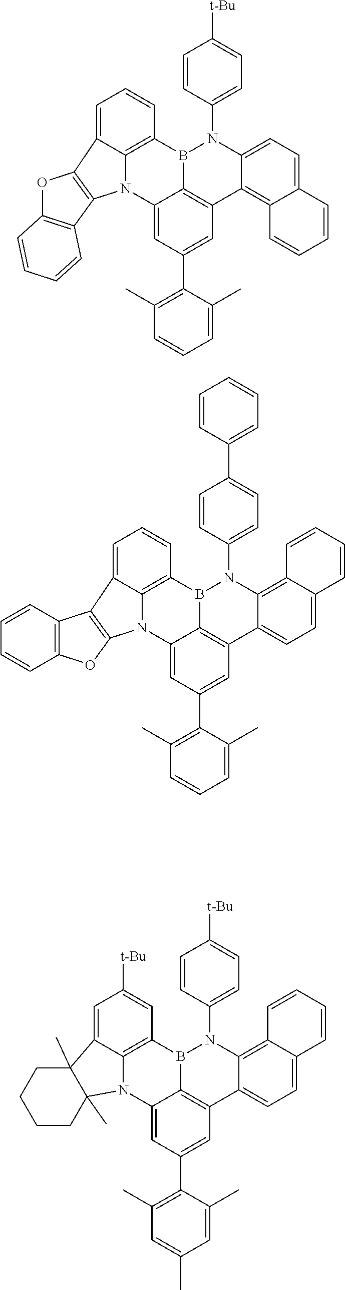 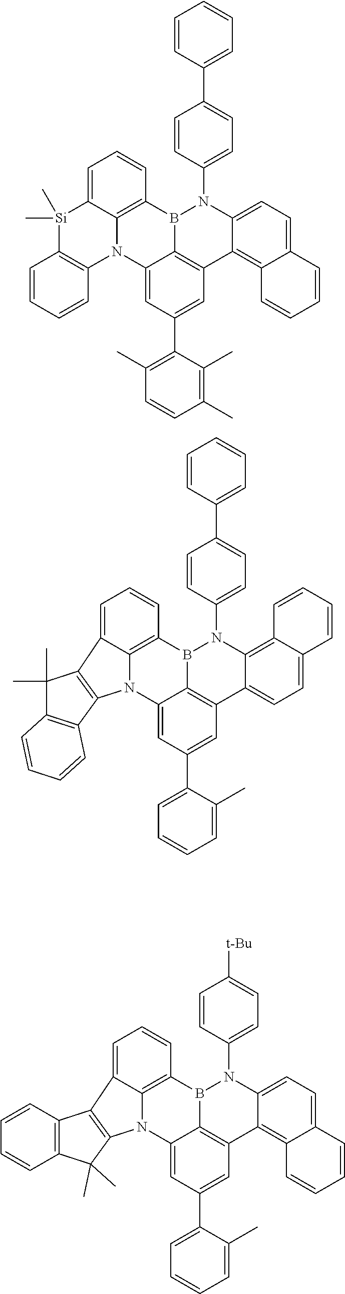 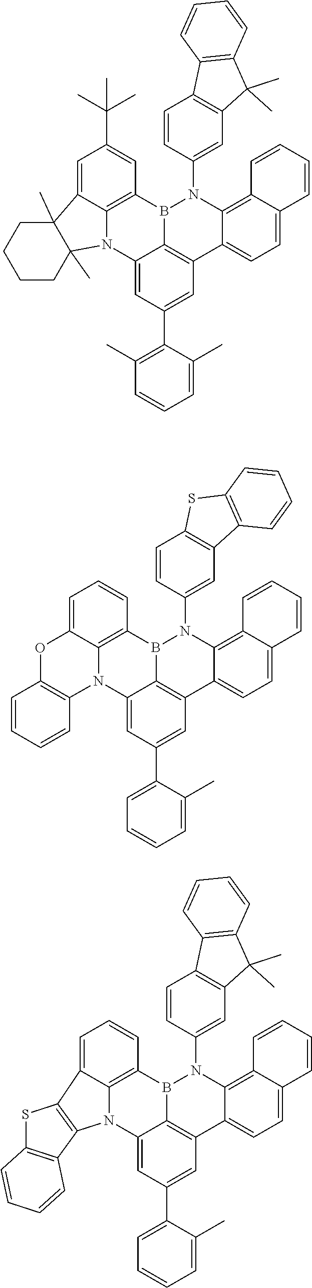 [SMILES: Cc1cccc(C)c1-c1cc2c3c(c1)N1c4c(cc(C(C)(C)C)cc4C4(C)CCCCC14C)B3N(c1ccc3c(c1)C(C)(C)c1ccccc1-3)c1c-2ccc2ccccc12 ; Cc1ccccc1-c1cc2c3c(c1)N1c4ccccc4Oc4cccc(c41)B3N(c1ccc3sc4ccccc4c3c1)c1c-2ccc2ccccc12 ; Cc1ccccc1-c1cc2c3c(c1)-n1c4c(cccc4c4sc5ccccc5c41)B3N(c1ccc3c(c1)C(C)(C)c1ccccc1-3)c1c-2ccc2ccccc12] 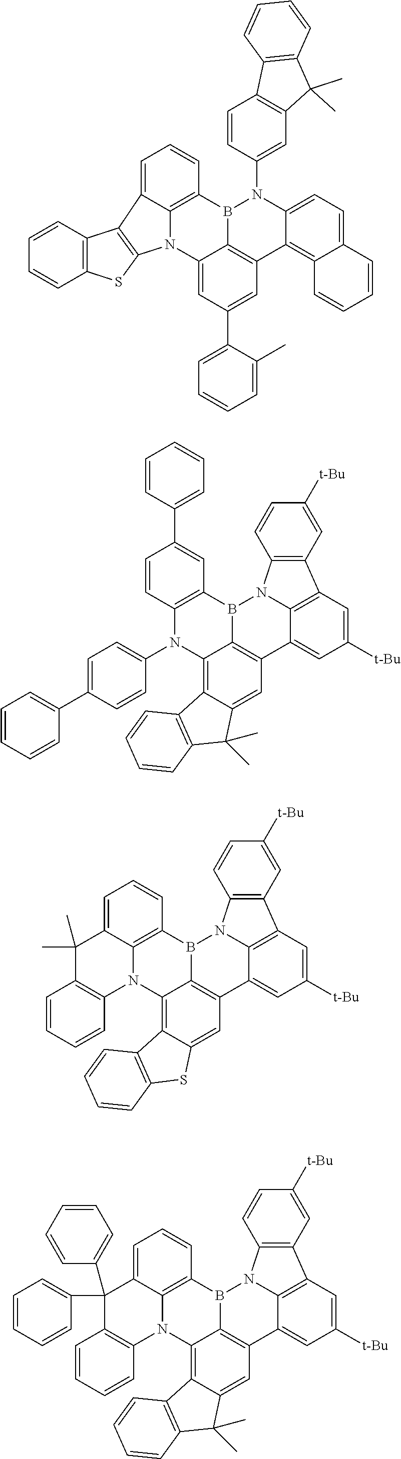 [SMILES: Cc1ccccc1-c1cc2c3c(c1)-n1c4sc5ccccc5c4c4cccc(c41)B3N(c1ccc3c(c1)C(C)(C)c1ccccc1-3)c1ccc3ccccc3c1-2 ; CC(C)(C)c1ccc2c(c1)c1cc(C(C)(C)C)cc3c1n2B1c2cc(-c4ccccc4)ccc2N(c2ccc(-c4ccccc4)cc2)c2c1c-3cc1c2-c2ccccc2C1(C)C ; CC(C)(C)c1ccc2c(c1)c1cc(C(C)(C)C)cc3c1n2B1c2cccc4c2N(c2ccccc2C4(C)C)c2c1c-3cc1sc3ccccc3c21 ; CC(C)(C)c1ccc2c(c1)c1cc(C(C)(C)C)cc3c1n2B1c2cccc4c2N(c2ccccc2C4(c2ccccc2)c2ccccc2)c2c1c-3cc1c2-c2ccccc2C1(C)C] 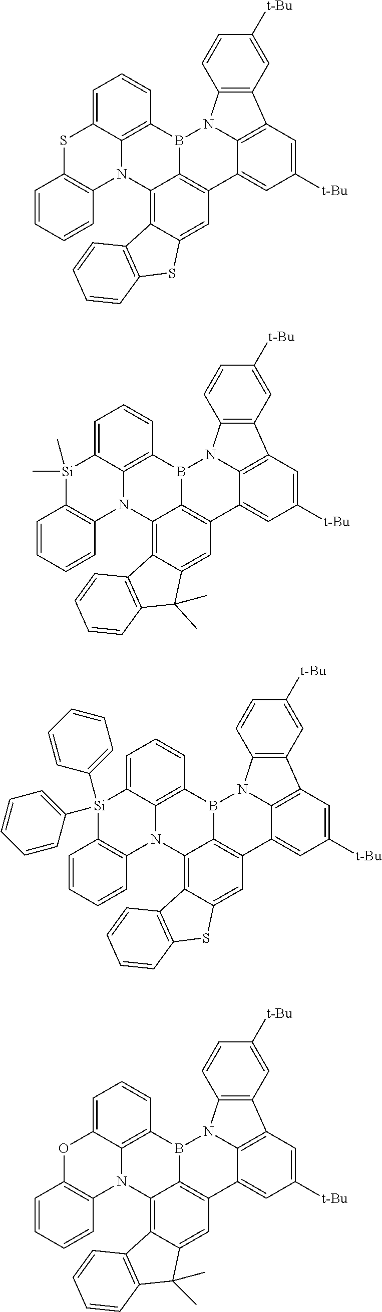 [SMILES: CC(C)(C)c1ccc2c(c1)c1cc(C(C)(C)C)cc3c1n2B1c2cccc4c2N(c2ccccc2S4)c2c1c-3cc1sc3ccccc3c21 ; CC(C)(C)c1ccc2c(c1)c1cc(C(C)(C)C)cc3c1n2B1c2cccc4c2N(c2ccccc2[Si]4(C)C)c2c1c-3cc1c2-c2ccccc2C1(C)C ; CC(C)(C)c1ccc2c(c1)c1cc(C(C)(C)C)cc3c1n2B1c2cccc4c2N(c2ccccc2[Si]4(c2ccccc2)c2ccccc2)c2c1c-3cc1sc3ccccc3c21 ; CC(C)(C)c1ccc2c(c1)c1cc(C(C)(C)C)cc3c1n2B1c2cccc4c2N(c2ccccc2O4)c2c1c-3cc1c2-c2ccccc2C1(C)C] 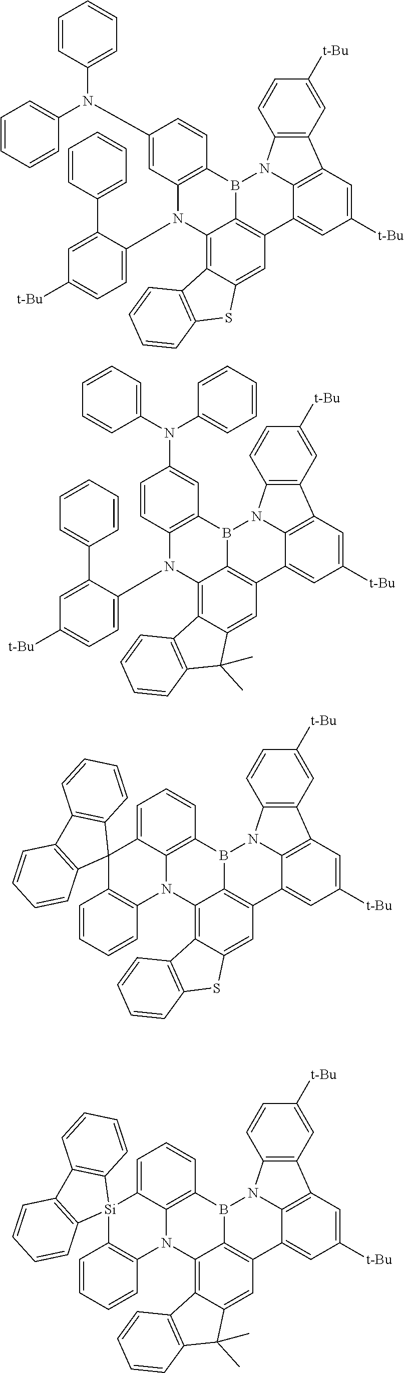 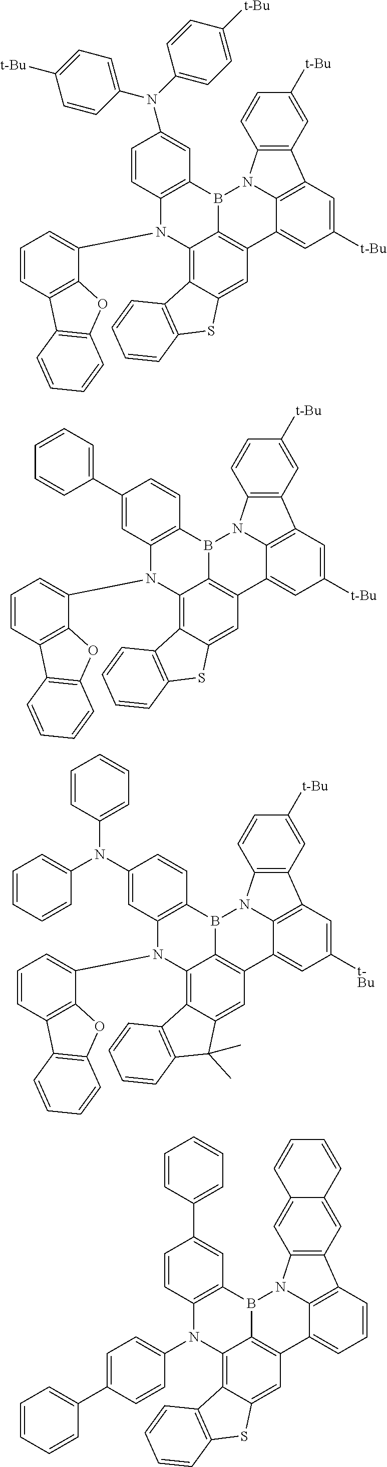 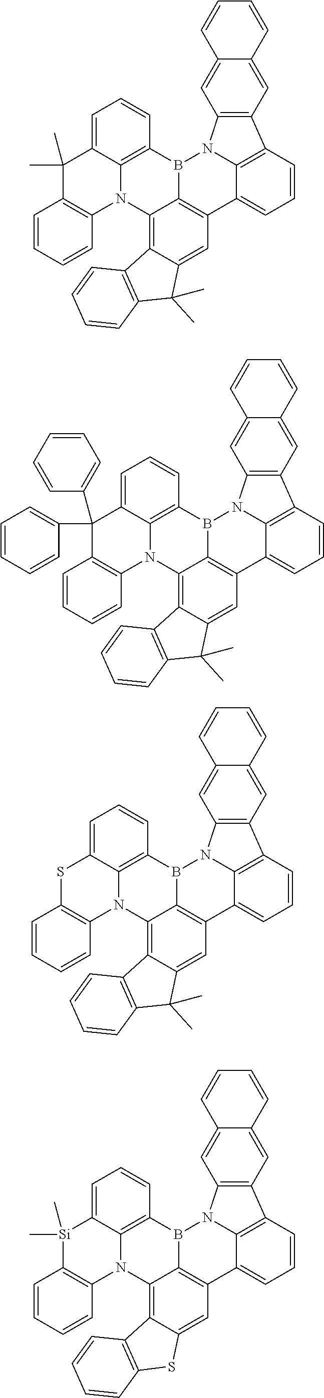 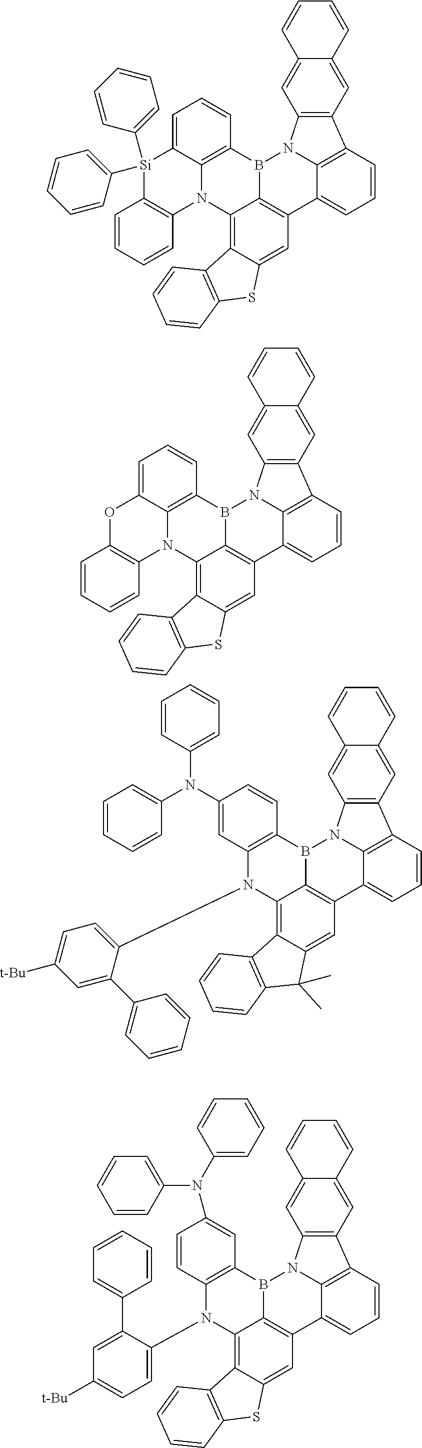 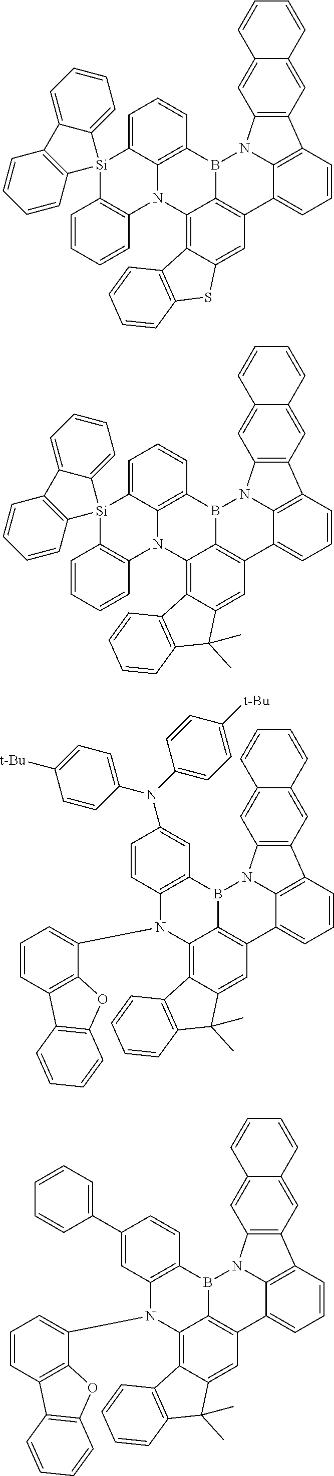 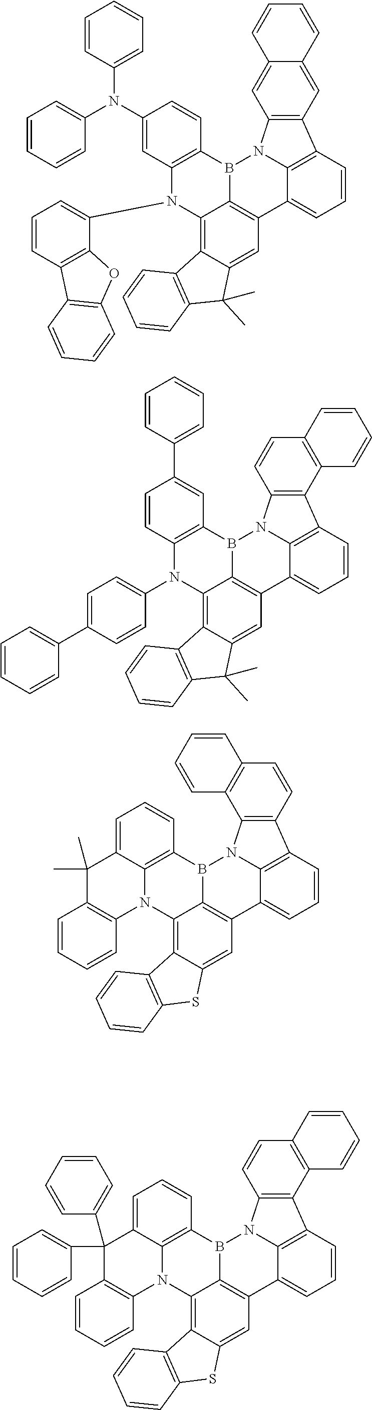 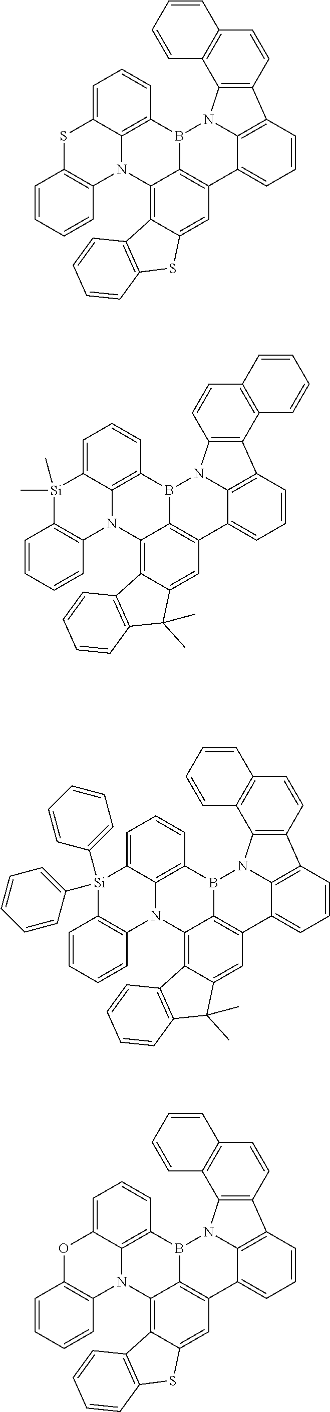 [SMILES: c1ccc2c(c1)Sc1cccc3c1N2c1c2c(cc4sc5ccccc5c14)-c1cccc4c5ccc6ccccc6c5n(c14)B32 ; CC1(C)c2ccccc2-c2c1cc1c3c2N2c4ccccc4[Si](C)(C)c4cccc(c42)B3n2c3ccc4ccccc4c3c3cccc-1c32 ; CC1(C)c2ccccc2-c2c1cc1c3c2N2c4ccccc4[Si](c4ccccc4)(c4ccccc4)c4cccc(c42)B3n2c3c-1cccc3c1ccc3ccccc3c12 ; c1ccc2c(c1)Oc1cccc3c1N2c1c2c(cc4sc5ccccc5c14)-c1cccc4c5ccc6ccccc6c5n(c14)B32] 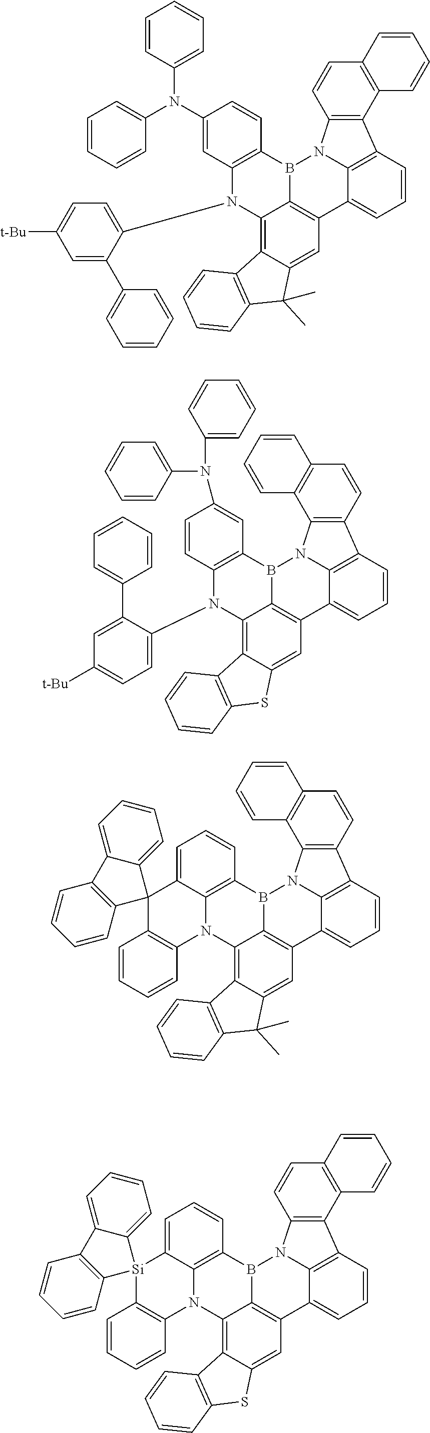 [SMILES: CC(C)(C)c1ccc(N2c3cc(N(c4ccccc4)c4ccccc4)ccc3B3c4c(cc5c(c42)-c2ccccc2C5(C)C)-c2cccc4c5c6ccccc6ccc5n3c24)c(-c2ccccc2)c1 ; CC(C)(C)c1ccc(N2c3ccc(N(c4ccccc4)c4ccccc4)cc3B3c4c(cc5sc6ccccc6c5c42)-c2cccc4c5ccc6ccccc6c5n3c24)c(-c2ccccc2)c1 ; CC1(C)c2ccccc2-c2c1cc1c3c2N2c4ccccc4C4(c5ccccc5-c5ccccc54)c4cccc(c42)B3n2c3c-1cccc3c1ccc3ccccc3c12 ; c1ccc2c(c1)-c1ccccc1[Si]21c2ccccc2N2c3c(cccc31)B1c3c(cc4sc5ccccc5c4c32)-c2cccc3c4c5ccccc5ccc4n1c23] 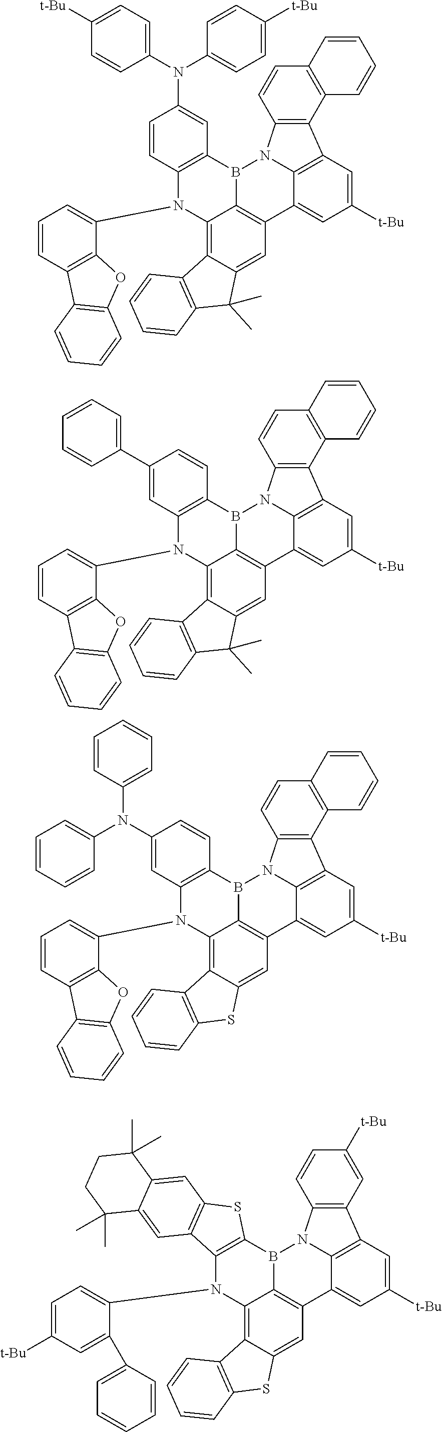 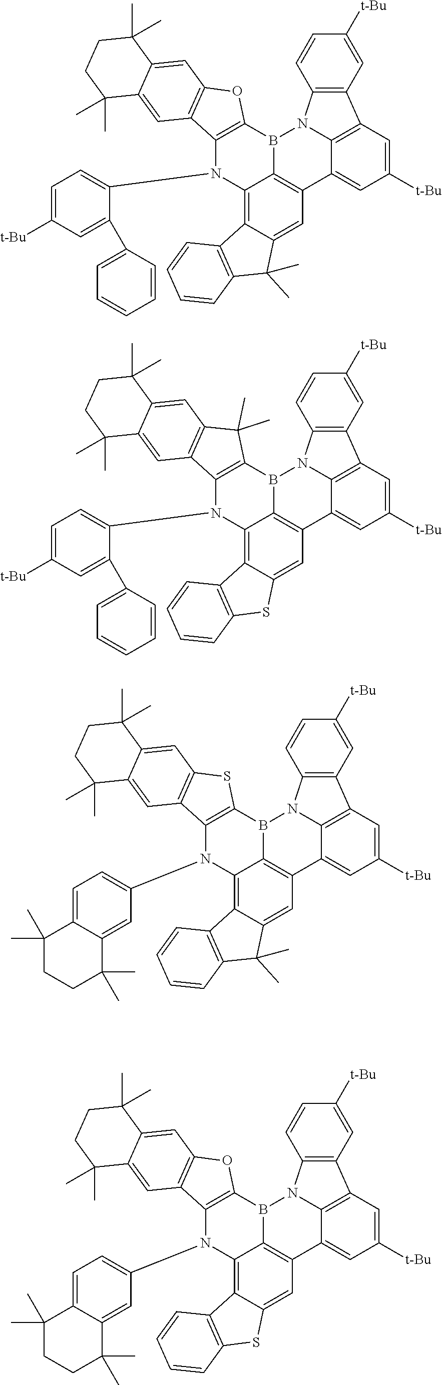 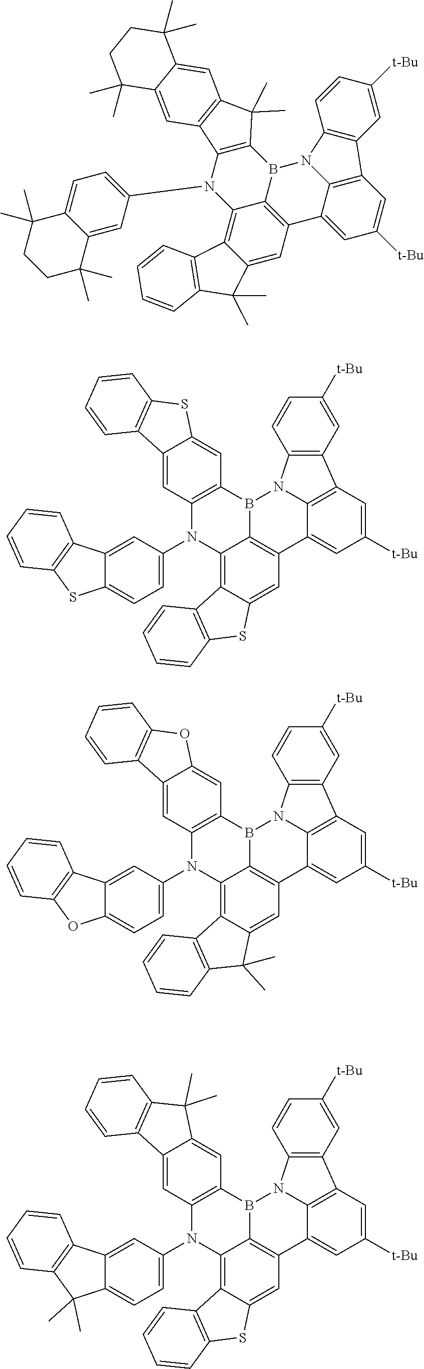 [SMILES: CC(C)(C)c1ccc2c(c1)c1cc(C(C)(C)C)cc3c1n2B1C2=C(c4cc5c(cc4C2(C)C)C(C)(C)CCC5(C)C)N(c2ccc4c(c2)C(C)(C)CCC4(C)C)c2c1c-3cc1c2-c2ccccc2C1(C)C ; CC(C)(C)c1ccc2c(c1)c1cc(C(C)(C)C)cc3c1n2B1c2cc4sc5ccccc5c4cc2N(c2ccc4sc5ccccc5c4c2)c2c1c-3cc1sc3ccccc3c21 ; CC(C)(C)c1ccc2c(c1)c1cc(C(C)(C)C)cc3c1n2B1c2cc4oc5ccccc5c4cc2N(c2ccc4oc5ccccc5c4c2)c2c1c-3cc1c2-c2ccccc2C1(C)C ; CC(C)(C)c1ccc2c(c1)c1cc(C(C)(C)C)cc3c1n2B1c2cc4c(cc2N(c2ccc5c(c2)-c2ccccc2C5(C)C)c2c1c-3cc1sc3ccccc3c21)-c1ccccc1C4(C)C] 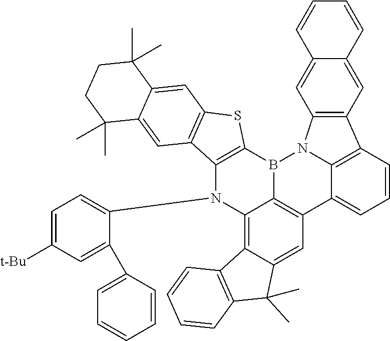 [SMILES: CC(C)(C)c1ccc(N2c3c4c(cc5c3-c3ccccc3C5(C)C)-c3cccc5c6cc7ccccc7cc6n(c35)B4c3sc4cc5c(cc4c32)C(C)(C)CCC5(C)C)c(-c2ccccc2)c1] 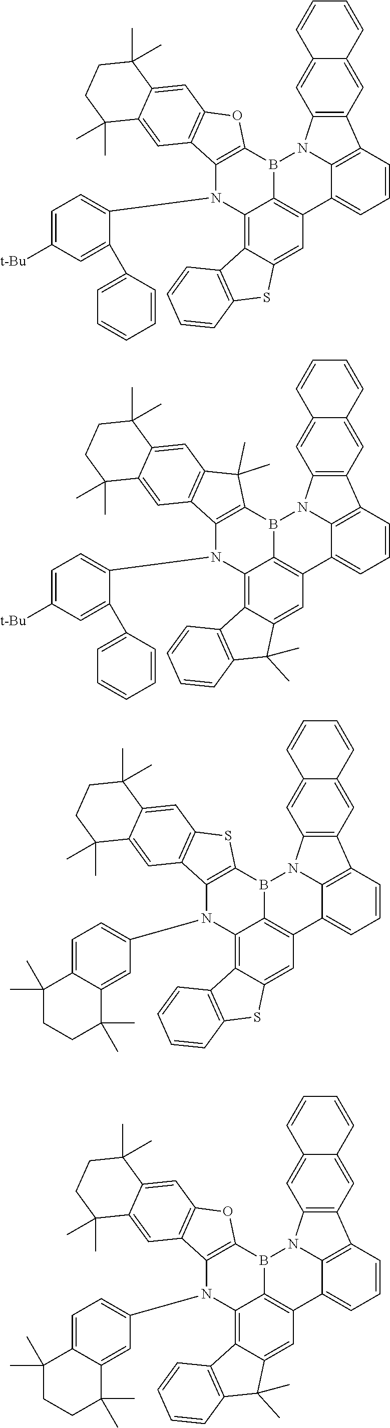 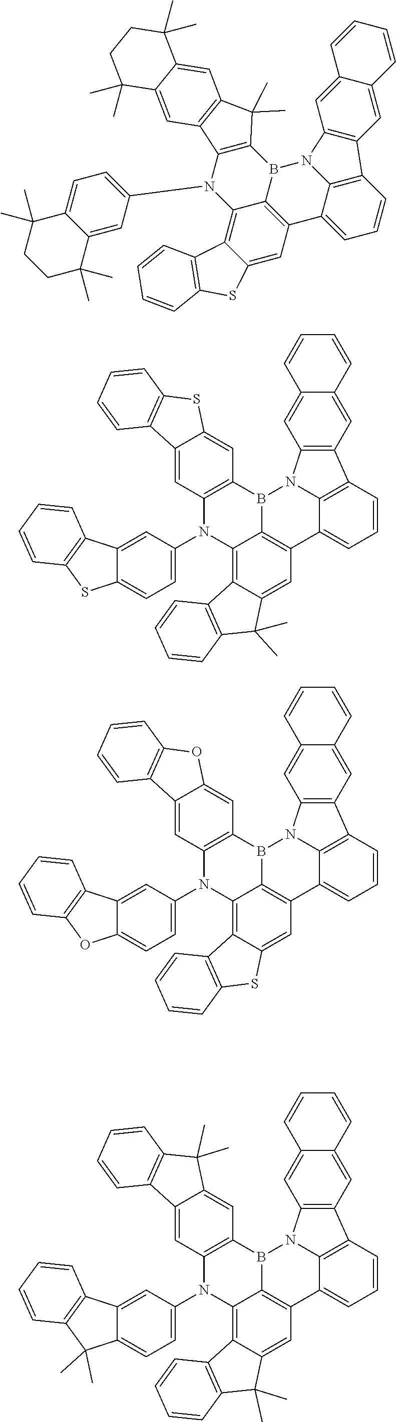 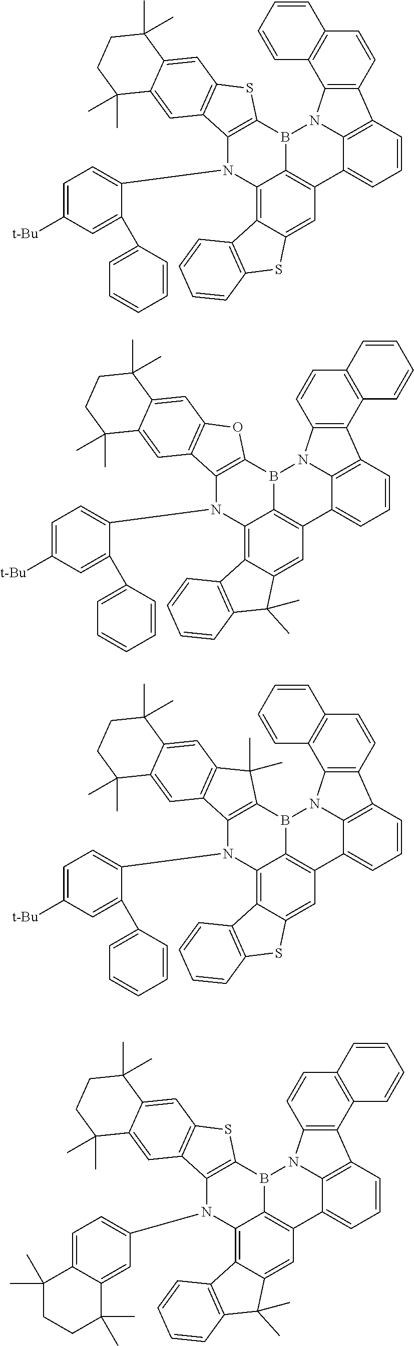 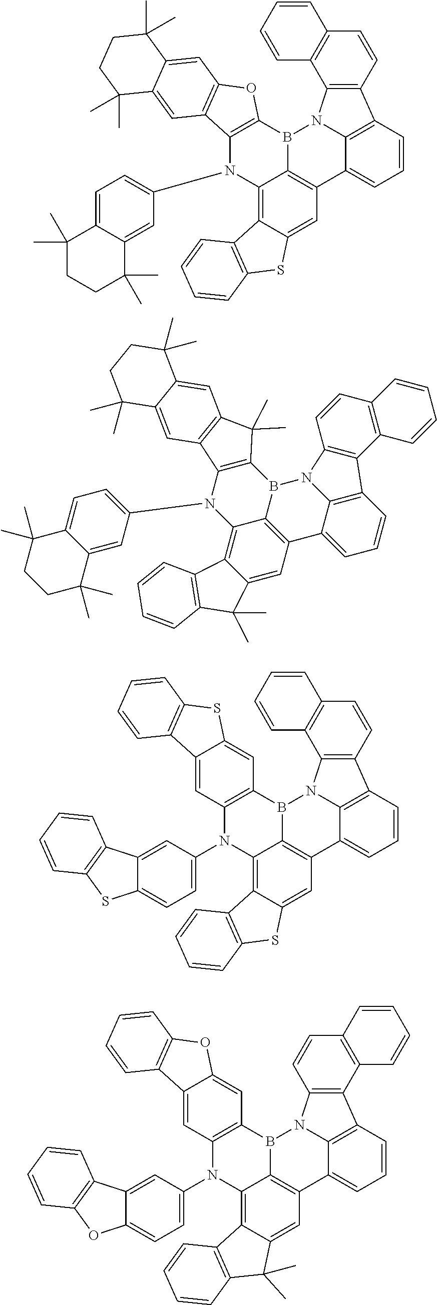 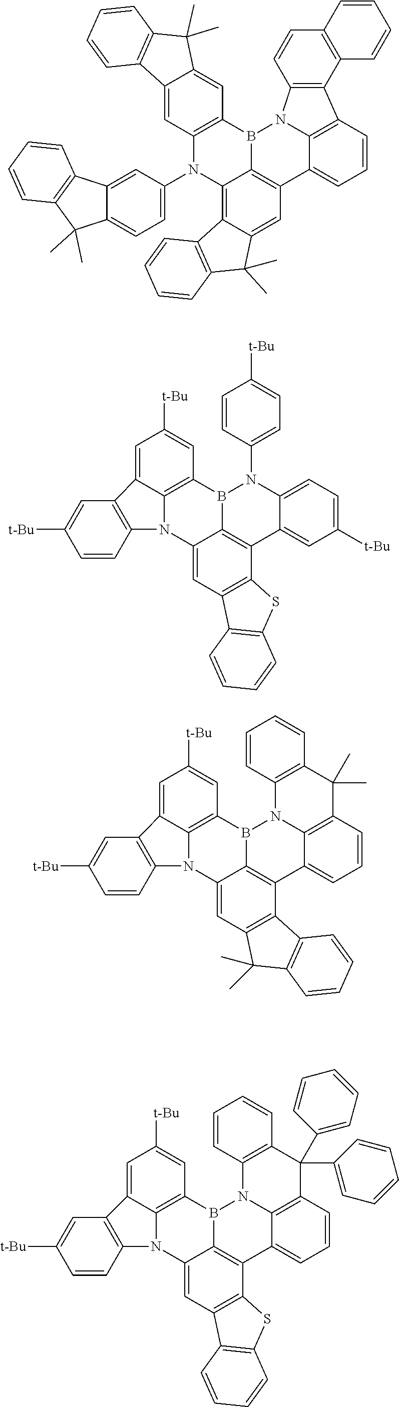 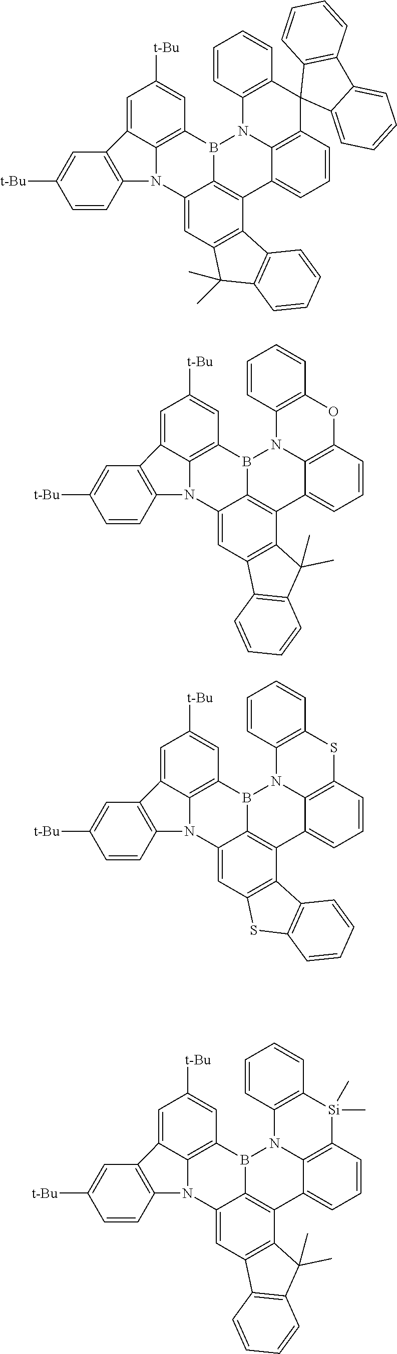 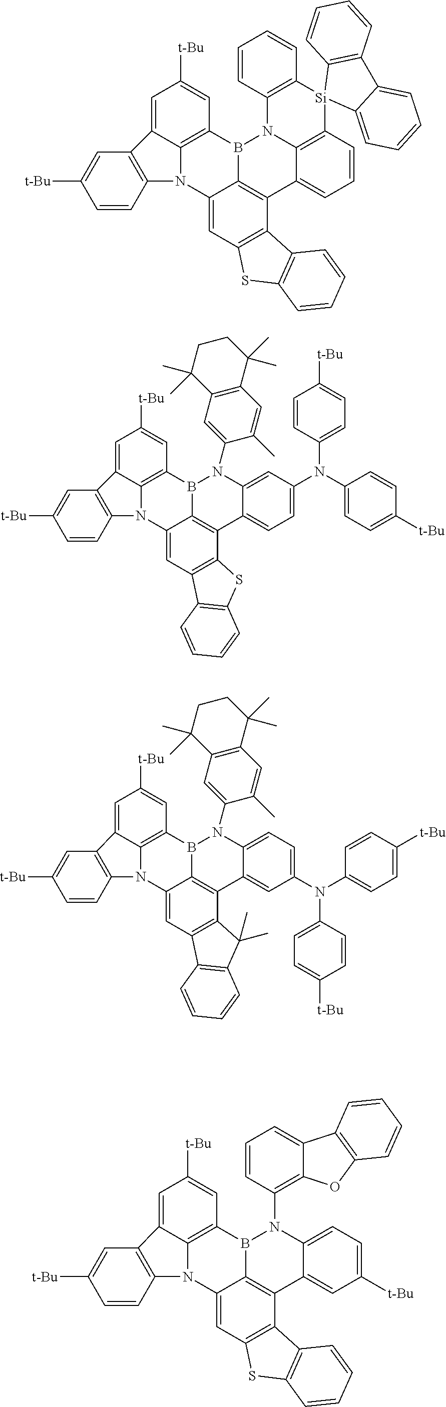 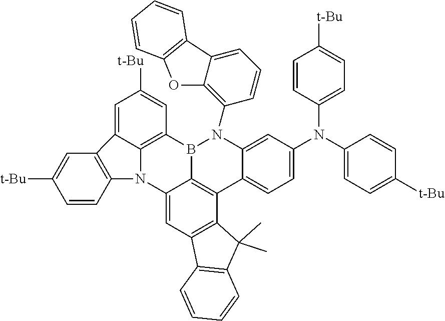 [SMILES: CC(C)(C)c1ccc(N(c2ccc(C(C)(C)C)cc2)c2ccc3c(c2)N(c2cccc4c2oc2ccccc24)B2c4c(cc5c(c4-3)C(C)(C)c3ccccc3-5)-n3c4ccc(C(C)(C)C)cc4c4cc(C(C)(C)C)cc2c43)cc1] 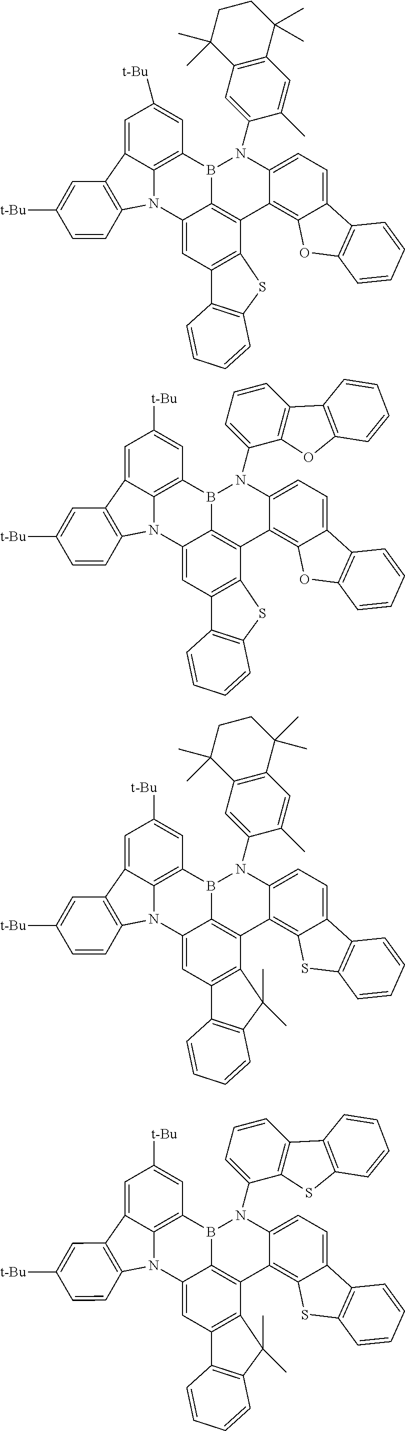 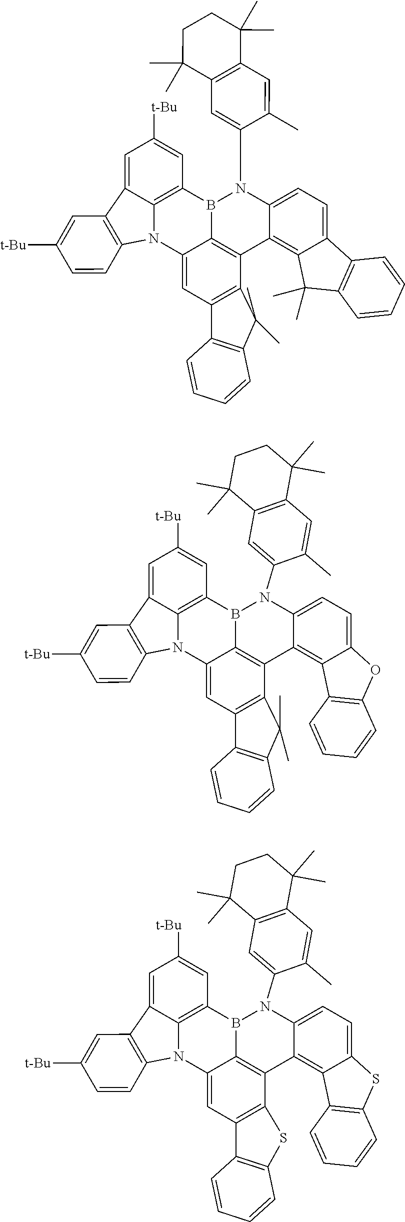 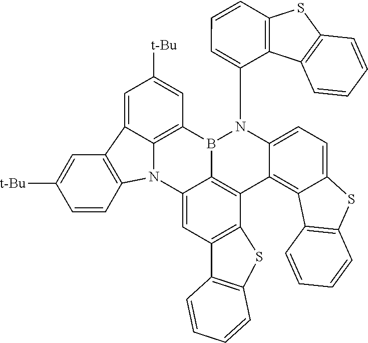 [SMILES: CC(C)(C)c1ccc2c(c1)c1cc(C(C)(C)C)cc3c1n2-c1cc2c(sc4ccccc42)c2c1B3N(c1cccc3sc4ccccc4c13)c1ccc3sc4ccccc4c3c1-2] 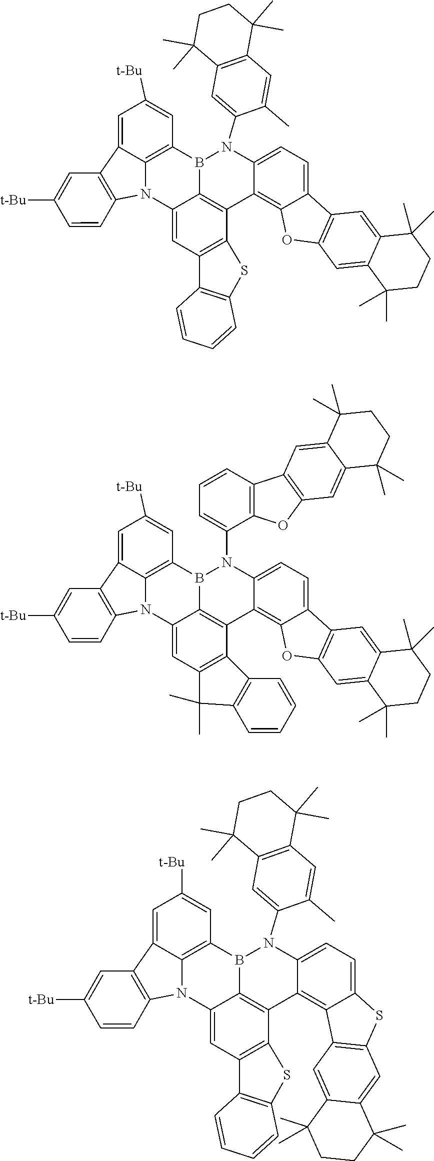 [SMILES: Cc1cc2c(cc1N1B3c4c(cc5c(sc6ccccc65)c4-c4c1ccc1c4oc4cc5c(cc41)C(C)(C)CCC5(C)C)-n1c4ccc(C(C)(C)C)cc4c4cc(C(C)(C)C)cc3c41)C(C)(C)CCC2(C)C ; CC(C)(C)c1ccc2c(c1)c1cc(C(C)(C)C)cc3c1n2-c1cc2c(c4c1B3N(c1cccc3c1oc1cc5c(cc13)C(C)(C)CCC5(C)C)c1ccc3c(oc5cc6c(cc53)C(C)(C)CCC6(C)C)c1-4)-c1ccccc1C2(C)C ; Cc1cc2c(cc1N1B3c4c(cc5c(sc6ccccc65)c4-c4c1ccc1sc5cc6c(cc5c41)C(C)(C)CCC6(C)C)-n1c4ccc(C(C)(C)C)cc4c4cc(C(C)(C)C)cc3c41)C(C)(C)CCC2(C)C] 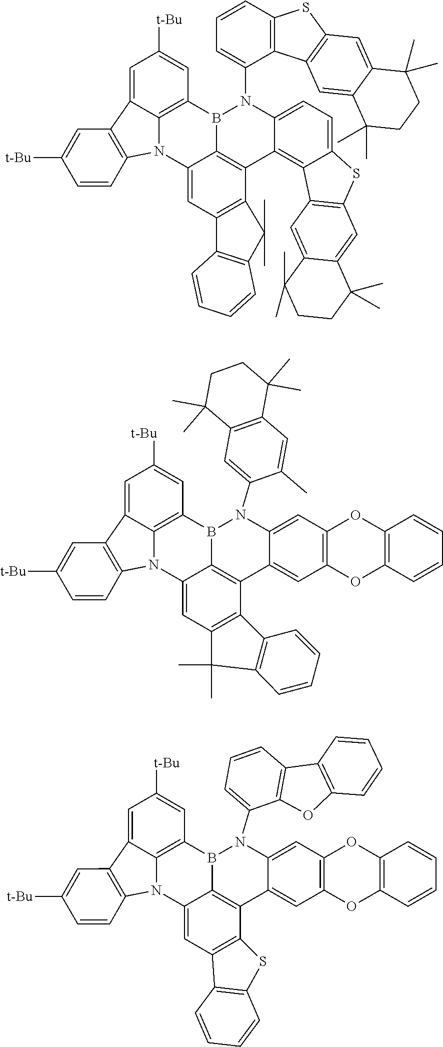 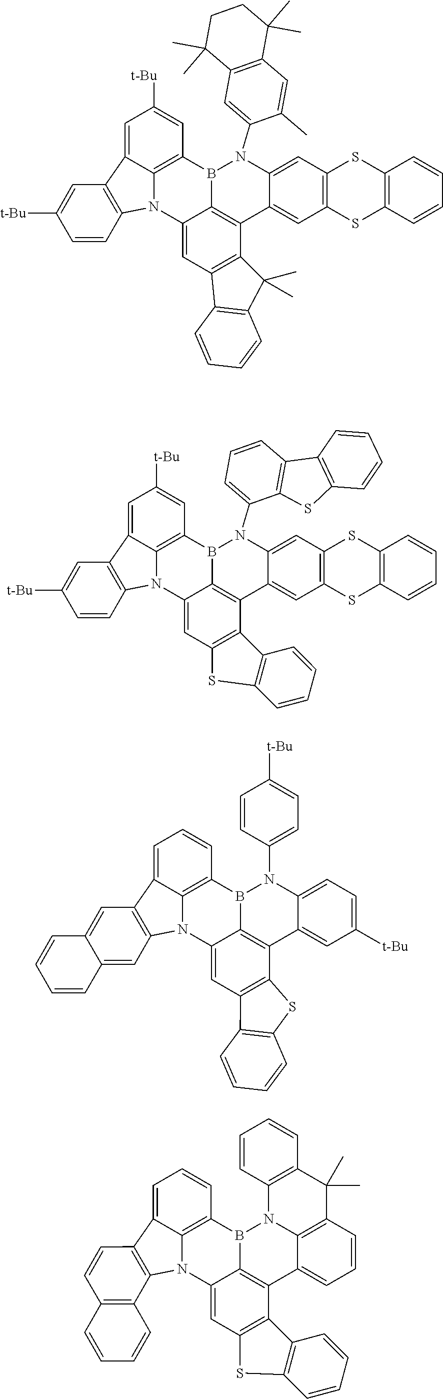 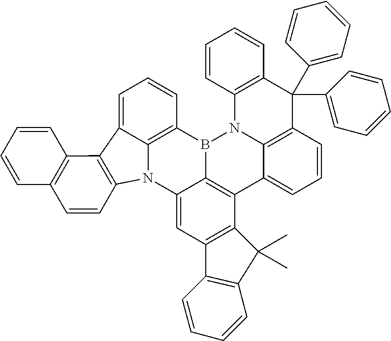 [SMILES: CC1(C)c2ccccc2-c2cc3c4c(c21)-c1cccc2c1N(B4c1cccc4c5c6ccccc6ccc5n-3c14)c1ccccc1C2(c1ccccc1)c1ccccc1] 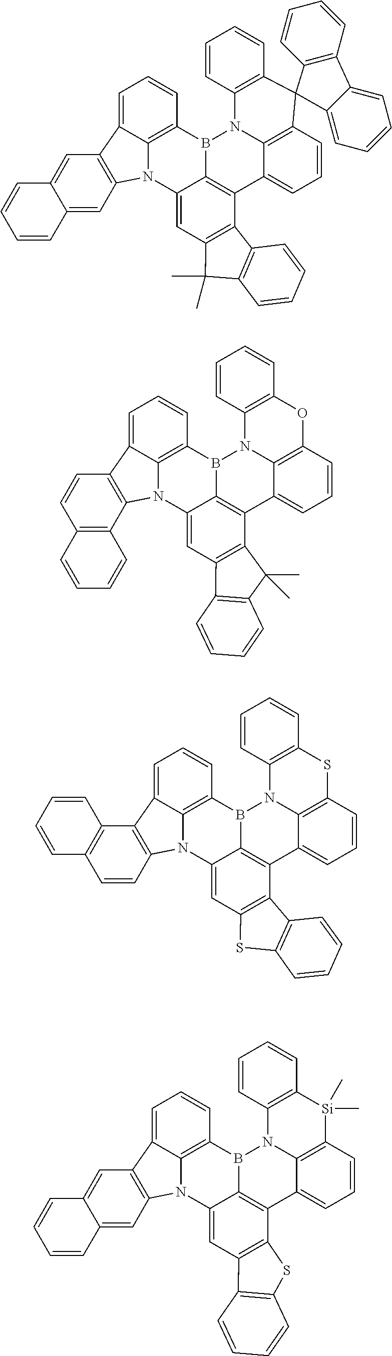 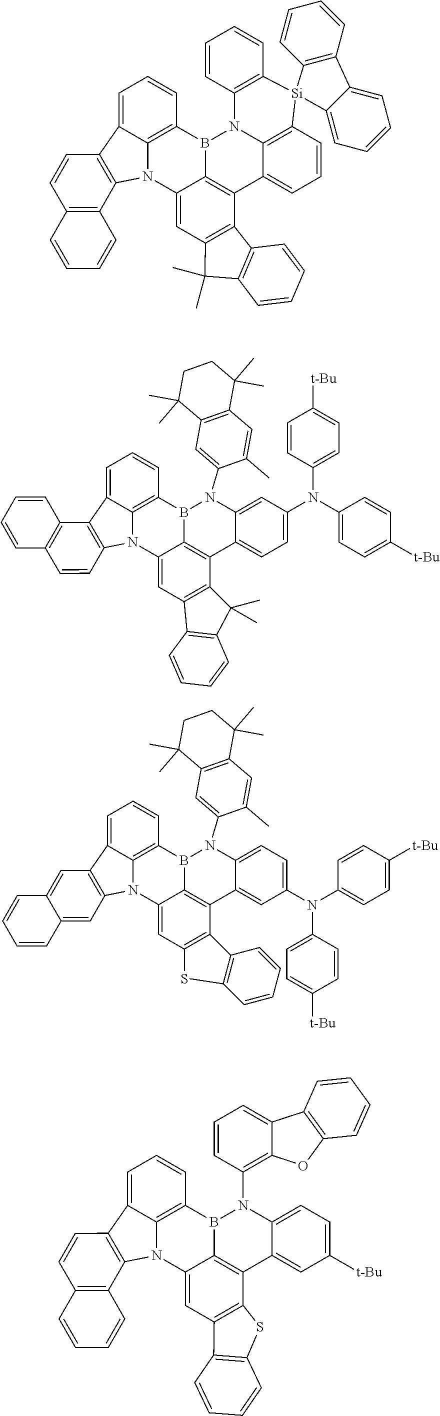 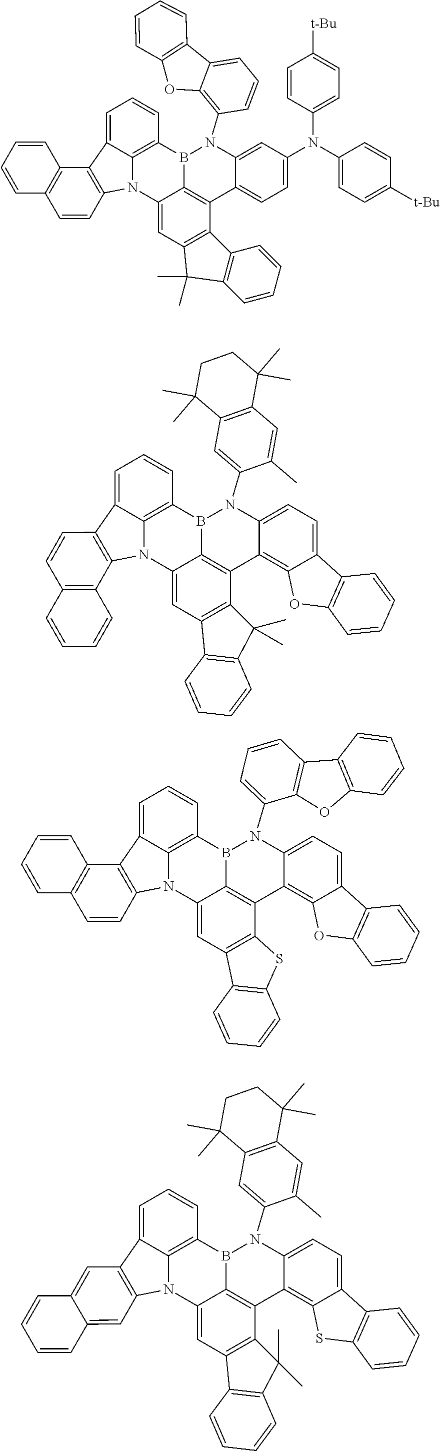 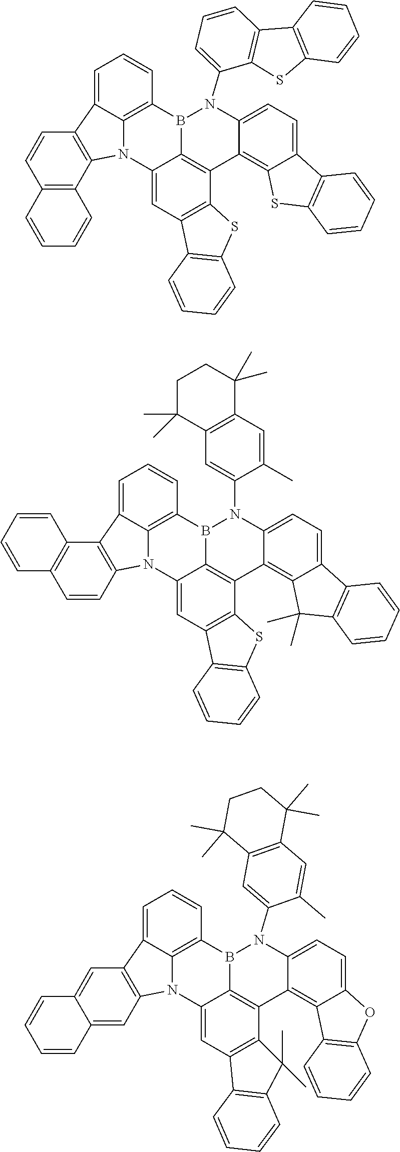 [SMILES: c1ccc2c(c1)ccc1c3cccc4c3n(c21)-c1cc2c(sc3ccccc32)c2c1B4N(c1cccc3c1sc1ccccc13)c1ccc3c(sc4ccccc43)c1-2 ; Cc1cc2c(cc1N1B3c4c(cc5c(sc6ccccc65)c4-c4c1ccc1c4C(C)(C)c4ccccc4-1)-n1c4ccc5ccccc5c4c4cccc3c41)C(C)(C)CCC2(C)C ; Cc1cc2c(cc1N1B3c4c(cc5c(c4-c4c1ccc1oc6ccccc6c41)C(C)(C)c1ccccc1-5)-n1c4cc5ccccc5cc4c4cccc3c41)C(C)(C)CCC2(C)C] 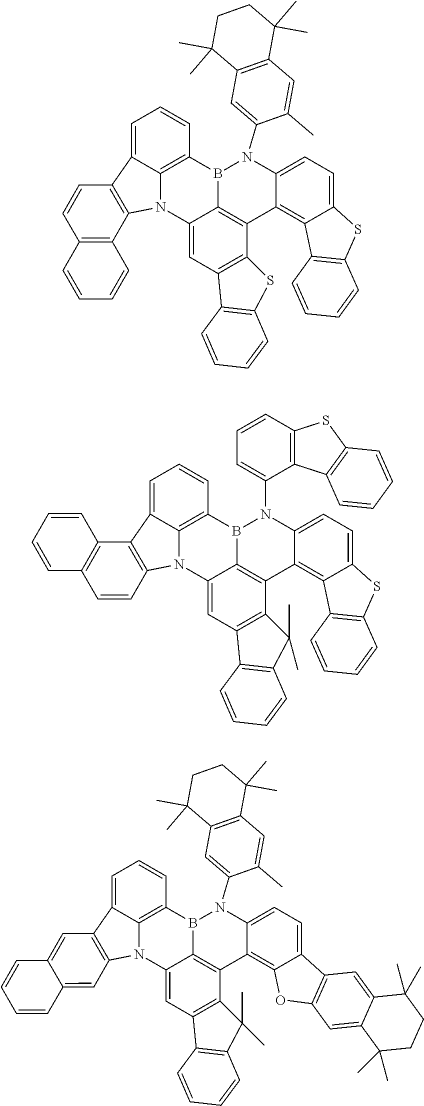 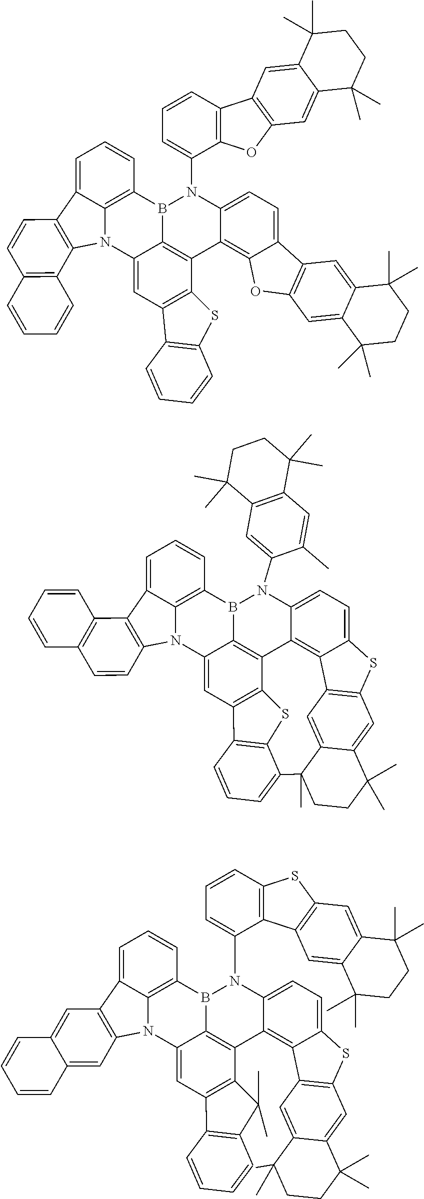 [SMILES: CC1(C)CCC(C)(C)c2cc3c(cc21)oc1c(N2B4c5c(cc6c(sc7ccccc76)c5-c5c2ccc2c5oc5cc6c(cc52)C(C)(C)CCC6(C)C)-n2c5c4cccc5c4ccc5ccccc5c42)cccc13 ; Cc1cc2c(cc1N1B3c4c(cc5c6sc7c(cccc75)C5(C)CCC(C)(C)c7cc8sc9ccc1c(c9c8cc75)-c46)-n1c4ccc5ccccc5c4c4cccc3c41)C(C)(C)CCC2(C)C ; CC1(C)CCC(C)(C)c2cc3c(cc21)sc1cccc(N2B4c5c(cc6c(c5-c5c2ccc2sc7cc8c(cc7c52)C(C)(C)CCC8(C)C)C(C)(C)c2ccccc2-6)-n2c5cc6ccccc6cc5c5cccc4c52)c13] 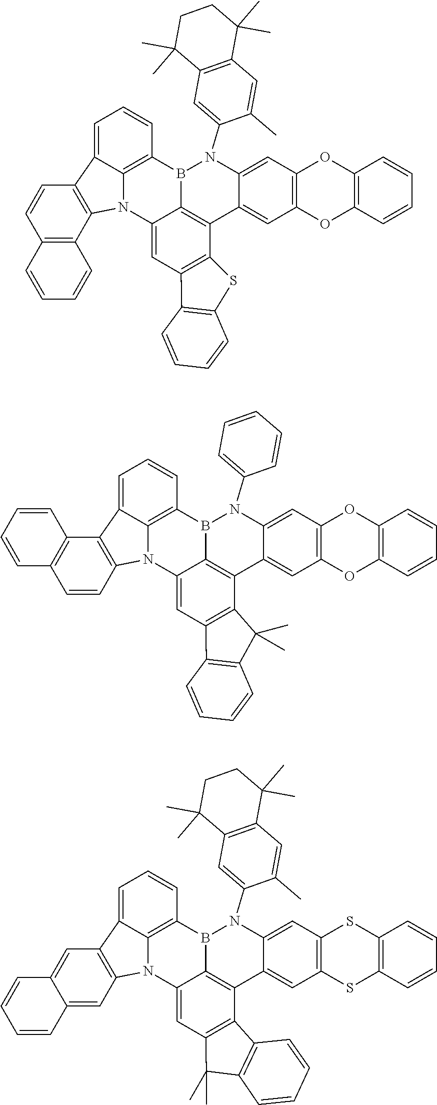 [SMILES: Cc1cc2c(cc1N1B3c4c(cc5c(sc6ccccc65)c4-c4cc5c(cc41)Oc1ccccc1O5)-n1c4c3cccc4c3ccc4ccccc4c31)C(C)(C)CCC2(C)C ; CC1(C)c2ccccc2-c2cc3c4c(c21)-c1cc2c(cc1N(c1ccccc1)B4c1cccc4c5c6ccccc6ccc5n-3c14)Oc1ccccc1O2 ; Cc1cc2c(cc1N1B3c4c(cc5c(c4-c4cc6c(cc41)Sc1ccccc1S6)-c1ccccc1C5(C)C)-n1c4cc5ccccc5cc4c4cccc3c41)C(C)(C)CCC2(C)C] 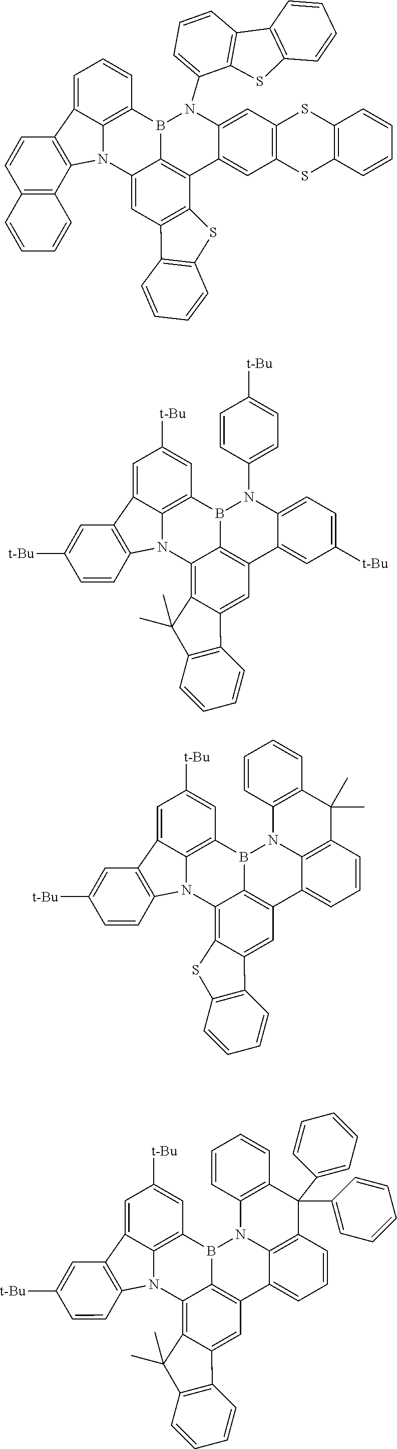 [SMILES: c1ccc2c(c1)Sc1cc3c(cc1S2)N(c1cccc2c1sc1ccccc12)B1c2c(cc4c(sc5ccccc54)c2-3)-n2c3c1cccc3c1ccc3ccccc3c12 ; CC(C)(C)c1ccc(N2B3c4c(cc5c(c4-n4c6ccc(C(C)(C)C)cc6c6cc(C(C)(C)C)cc3c64)C(C)(C)c3ccccc3-5)-c3cc(C(C)(C)C)ccc32)cc1 ; CC(C)(C)c1ccc2c(c1)c1cc(C(C)(C)C)cc3c1n2-c1c2c(cc4c1sc1ccccc14)-c1cccc4c1N(B23)c1ccccc1C4(C)C ; CC(C)(C)c1ccc2c(c1)c1cc(C(C)(C)C)cc3c1n2-c1c2c(cc4c1C(C)(C)c1ccccc1-4)-c1cccc4c1N(B23)c1ccccc1C4(c1ccccc1)c1ccccc1] 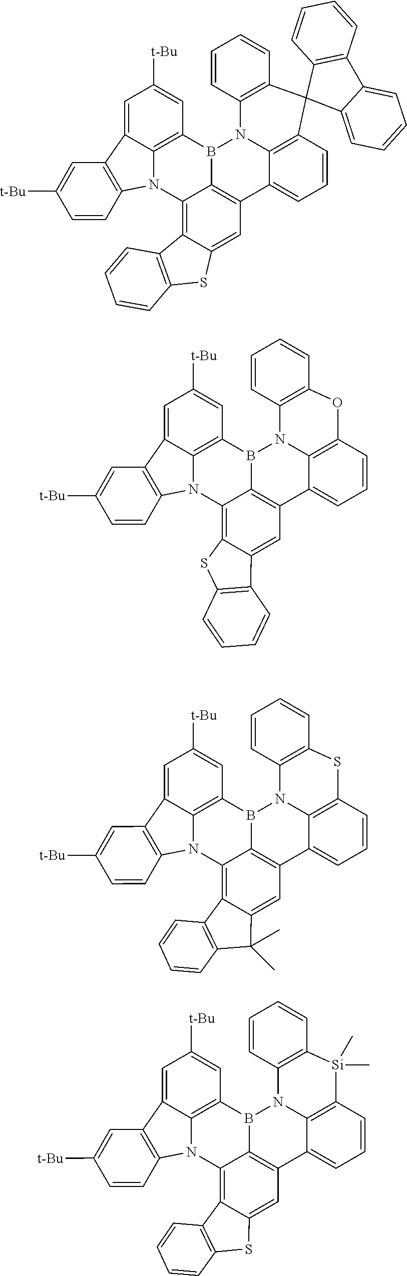 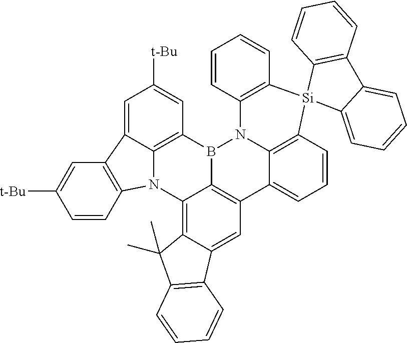 [SMILES: CC(C)(C)c1ccc2c(c1)c1cc(C(C)(C)C)cc3c1n2-c1c2c(cc4c1C(C)(C)c1ccccc1-4)-c1cccc4c1N(B23)c1ccccc1[Si]41c2ccccc2-c2ccccc21] 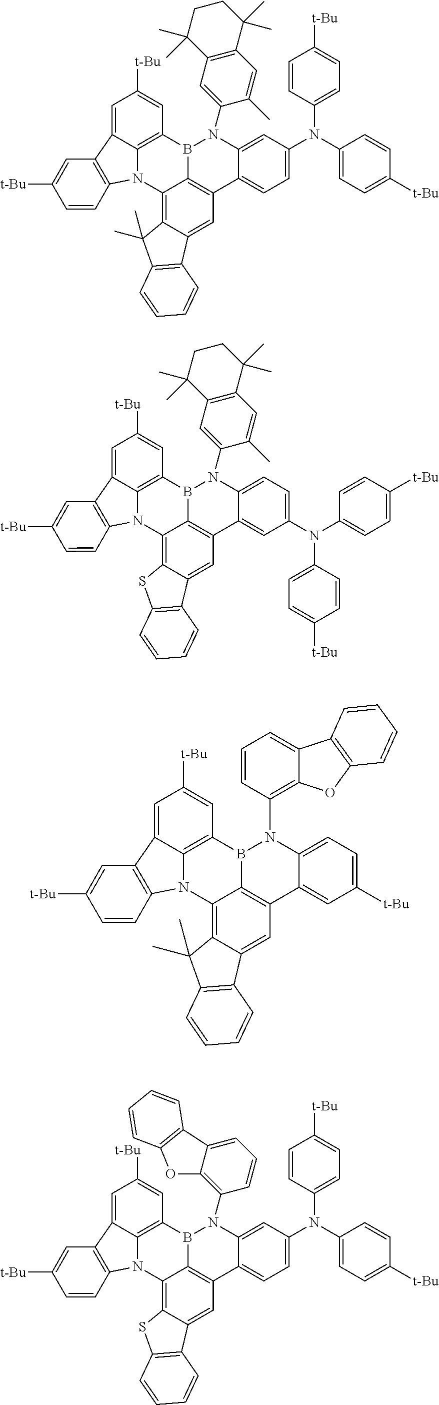 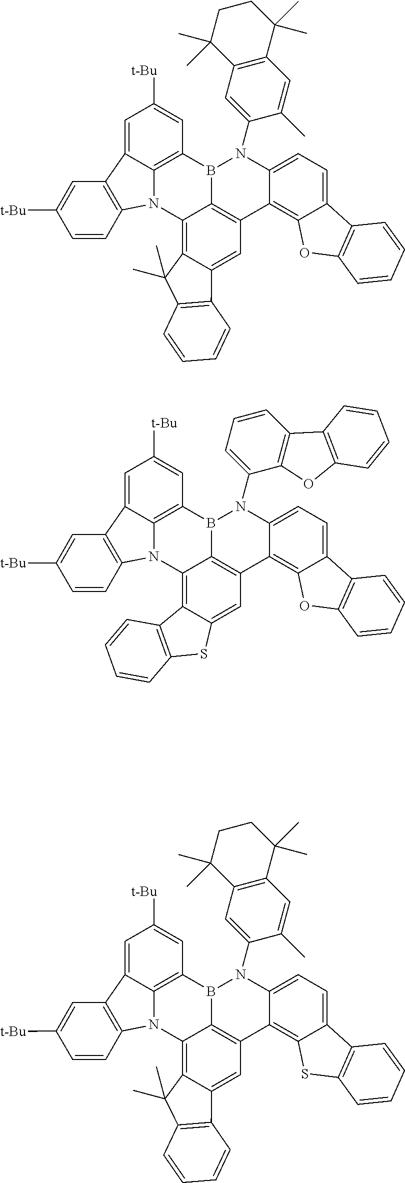 [SMILES: Cc1cc2c(cc1N1B3c4c(cc5c(c4-n4c6ccc(C(C)(C)C)cc6c6cc(C(C)(C)C)cc3c64)C(C)(C)c3ccccc3-5)-c3c1ccc1c3oc3ccccc31)C(C)(C)CCC2(C)C ; CC(C)(C)c1ccc2c(c1)c1cc(C(C)(C)C)cc3c1n2-c1c2c(cc4sc5ccccc5c14)-c1c(ccc4c1oc1ccccc14)N(c1cccc4c1oc1ccccc14)B23 ; Cc1cc2c(cc1N1B3c4c(cc5c(c4-n4c6ccc(C(C)(C)C)cc6c6cc(C(C)(C)C)cc3c64)C(C)(C)c3ccccc3-5)-c3c1ccc1c3sc3ccccc31)C(C)(C)CCC2(C)C] 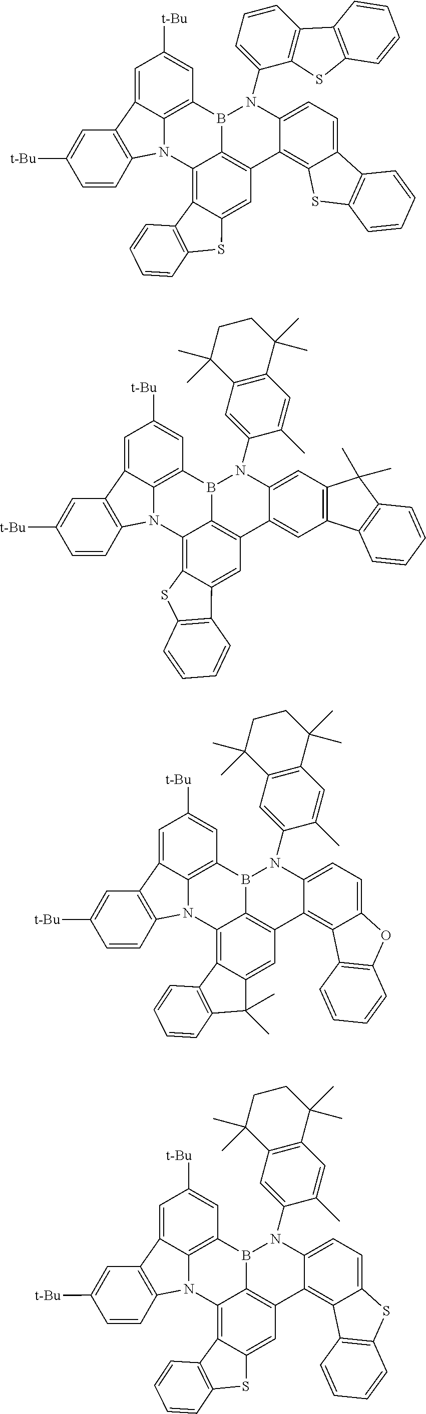 [SMILES: CC(C)(C)c1ccc2c(c1)c1cc(C(C)(C)C)cc3c1n2-c1c2c(cc4sc5ccccc5c14)-c1c(ccc4c1sc1ccccc14)N(c1cccc4c1sc1ccccc14)B23 ; Cc1cc2c(cc1N1B3c4c(cc5c(sc6ccccc65)c4-n4c5ccc(C(C)(C)C)cc5c5cc(C(C)(C)C)cc3c54)-c3cc4c(cc31)C(C)(C)c1ccccc1-4)C(C)(C)CCC2(C)C ; Cc1cc2c(cc1N1B3c4c(cc5c(c4-n4c6ccc(C(C)(C)C)cc6c6cc(C(C)(C)C)cc3c64)-c3ccccc3C5(C)C)-c3c1ccc1oc4ccccc4c31)C(C)(C)CCC2(C)C ; Cc1cc2c(cc1N1B3c4c(cc5sc6ccccc6c5c4-n4c5ccc(C(C)(C)C)cc5c5cc(C(C)(C)C)cc3c54)-c3c1ccc1sc4ccccc4c31)C(C)(C)CCC2(C)C] 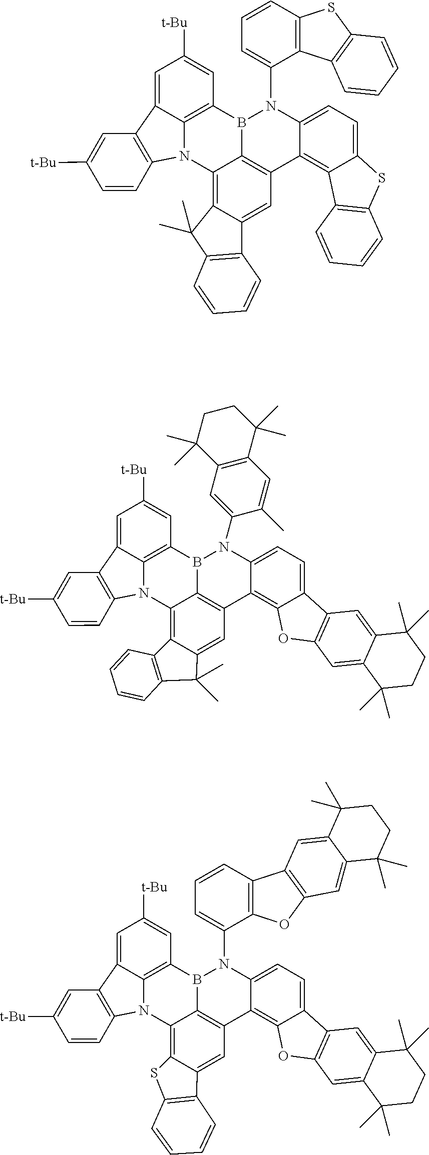 [SMILES: CC(C)(C)c1ccc2c(c1)c1cc(C(C)(C)C)cc3c1n2-c1c2c(cc4c1C(C)(C)c1ccccc1-4)-c1c(ccc4sc5ccccc5c14)N(c1cccc4sc5ccccc5c14)B23 ; Cc1cc2c(cc1N1B3c4c(cc5c(c4-n4c6ccc(C(C)(C)C)cc6c6cc(C(C)(C)C)cc3c64)-c3ccccc3C5(C)C)-c3c1ccc1c3oc3cc4c(cc31)C(C)(C)CCC4(C)C)C(C)(C)CCC2(C)C ; CC(C)(C)c1ccc2c(c1)c1cc(C(C)(C)C)cc3c1n2-c1c2c(cc4c1sc1ccccc14)-c1c(ccc4c1oc1cc5c(cc14)C(C)(C)CCC5(C)C)N(c1cccc4c1oc1cc5c(cc14)C(C)(C)CCC5(C)C)B23] 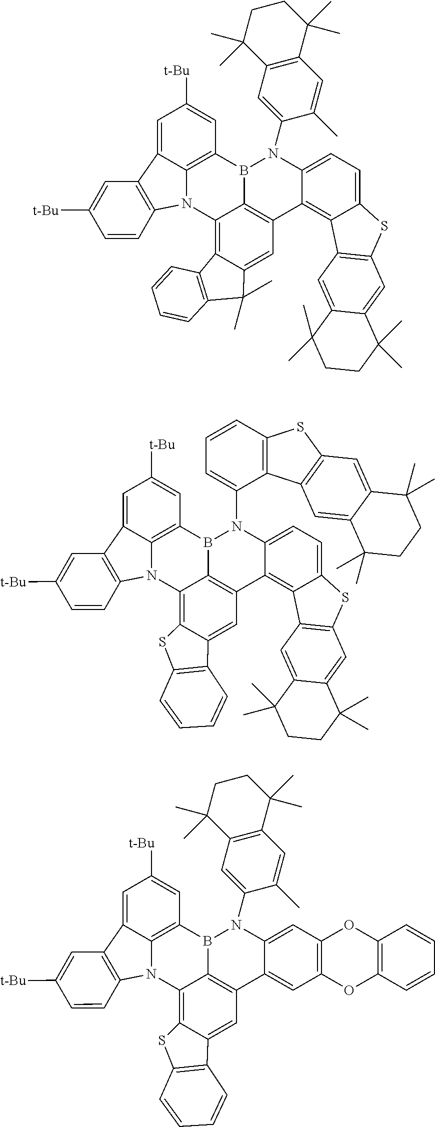 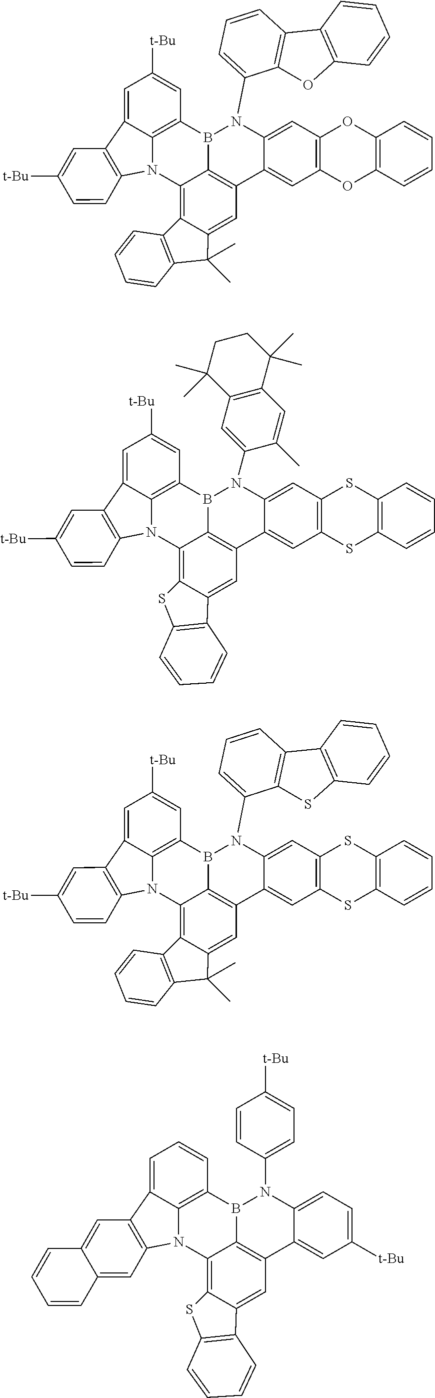 [SMILES: CC(C)(C)c1ccc2c(c1)c1cc(C(C)(C)C)cc3c1n2-c1c2c(cc4c1-c1ccccc1C4(C)C)-c1cc4c(cc1N(c1cccc5c1oc1ccccc15)B23)Oc1ccccc1O4 ; Cc1cc2c(cc1N1B3c4c(cc5c(sc6ccccc65)c4-n4c5ccc(C(C)(C)C)cc5c5cc(C(C)(C)C)cc3c54)-c3cc4c(cc31)Sc1ccccc1S4)C(C)(C)CCC2(C)C ; CC(C)(C)c1ccc2c(c1)c1cc(C(C)(C)C)cc3c1n2-c1c2c(cc4c1-c1ccccc1C4(C)C)-c1cc4c(cc1N(c1cccc5c1sc1ccccc15)B23)Sc1ccccc1S4 ; CC(C)(C)c1ccc(N2B3c4c(cc5c(sc6ccccc65)c4-n4c5cc6ccccc6cc5c5cccc3c54)-c3cc(C(C)(C)C)ccc32)cc1] 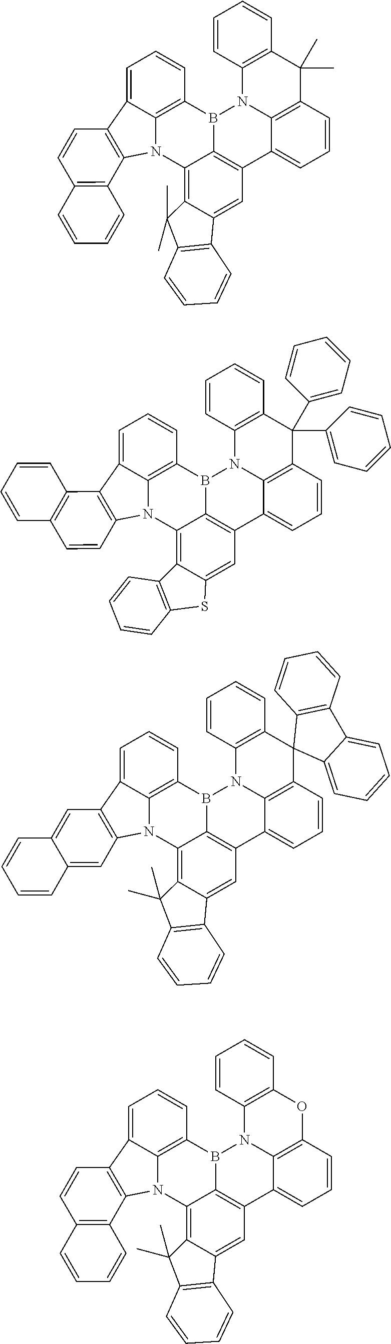 [SMILES: CC1(C)c2ccccc2N2B3c4c(cc5c(c4-n4c6c3cccc6c3ccc6ccccc6c34)C(C)(C)c3ccccc3-5)-c3cccc1c32 ; c1ccc(C2(c3ccccc3)c3ccccc3N3B4c5c(cc6sc7ccccc7c6c5-n5c6ccc7ccccc7c6c6cccc4c65)-c4cccc2c43)cc1 ; CC1(C)c2ccccc2-c2cc3c4c(c21)-n1c2cc5ccccc5cc2c2cccc(c21)B4N1c2ccccc2C2(c4ccccc4-c4ccccc42)c2cccc-3c21 ; CC1(C)c2ccccc2-c2cc3c4c(c21)-n1c2c(cccc2c2ccc5ccccc5c21)B4N1c2ccccc2Oc2cccc-3c21] 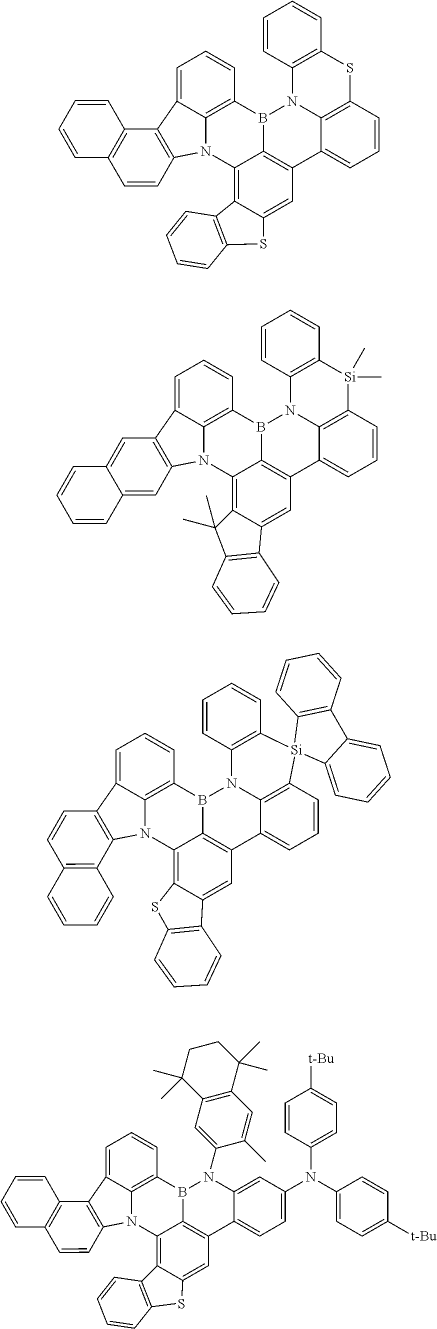 [SMILES: c1ccc2c(c1)Sc1cccc3c1N2B1c2c-3cc3sc4ccccc4c3c2-n2c3ccc4ccccc4c3c3cccc1c32 ; CC1(C)c2ccccc2-c2cc3c4c(c21)-n1c2cc5ccccc5cc2c2cccc(c21)B4N1c2ccccc2[Si](C)(C)c2cccc-3c21 ; c1ccc2c(c1)-c1ccccc1[Si]21c2ccccc2N2B3c4c(cc5c(sc6ccccc65)c4-n4c5c3cccc5c3ccc5ccccc5c34)-c3cccc1c32 ; Cc1cc2c(cc1N1B3c4c(cc5sc6ccccc6c5c4-n4c5ccc6ccccc6c5c5cccc3c54)-c3ccc(N(c4ccc(C(C)(C)C)cc4)c4ccc(C(C)(C)C)cc4)cc31)C(C)(C)CCC2(C)C] 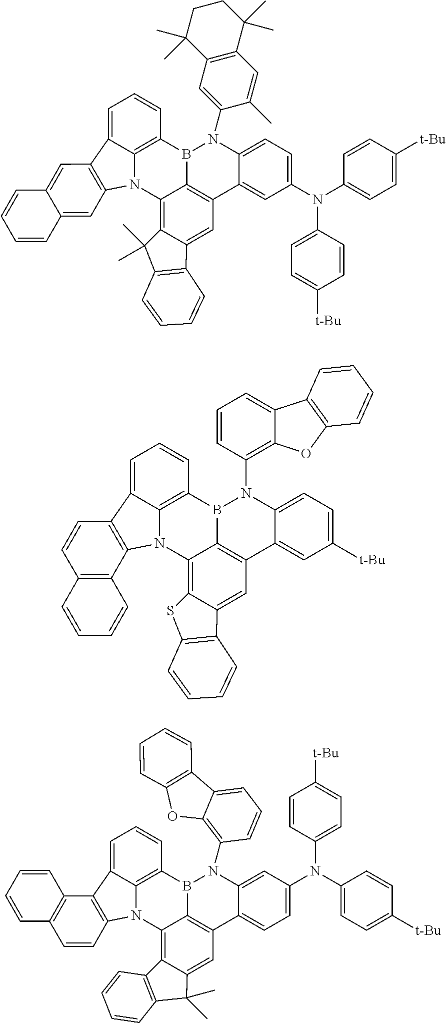 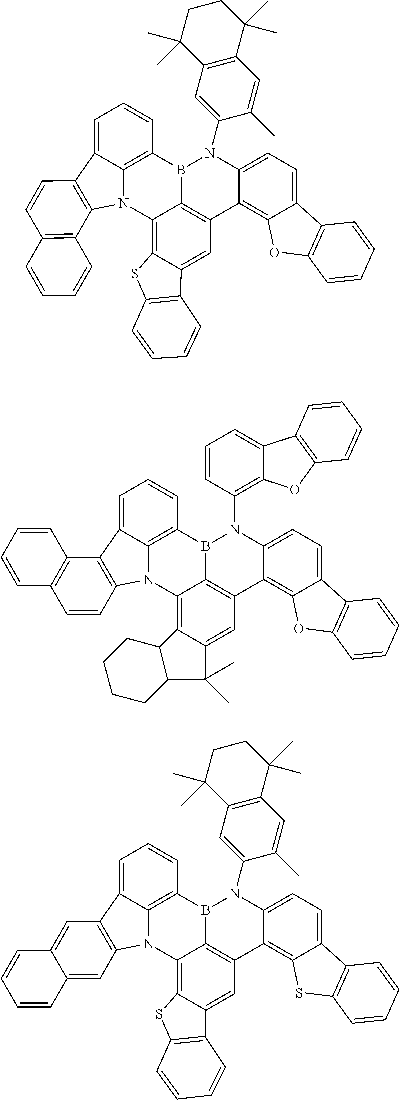 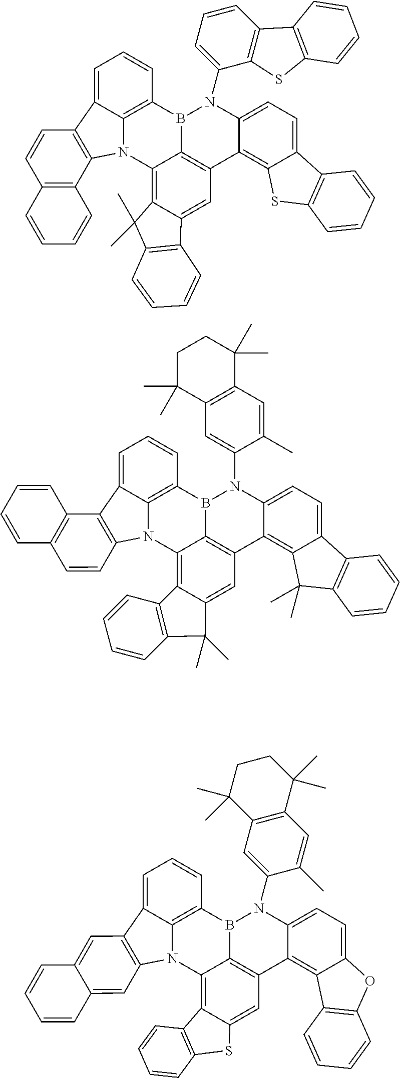 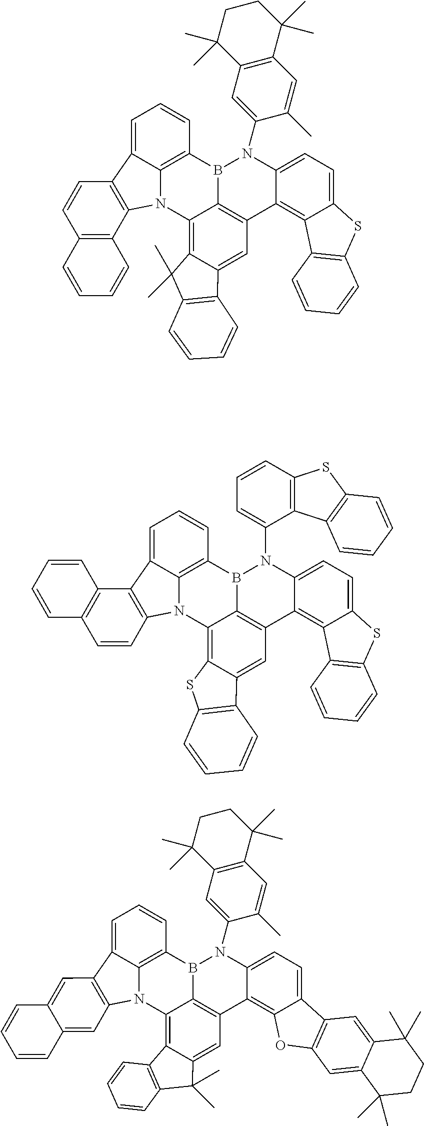 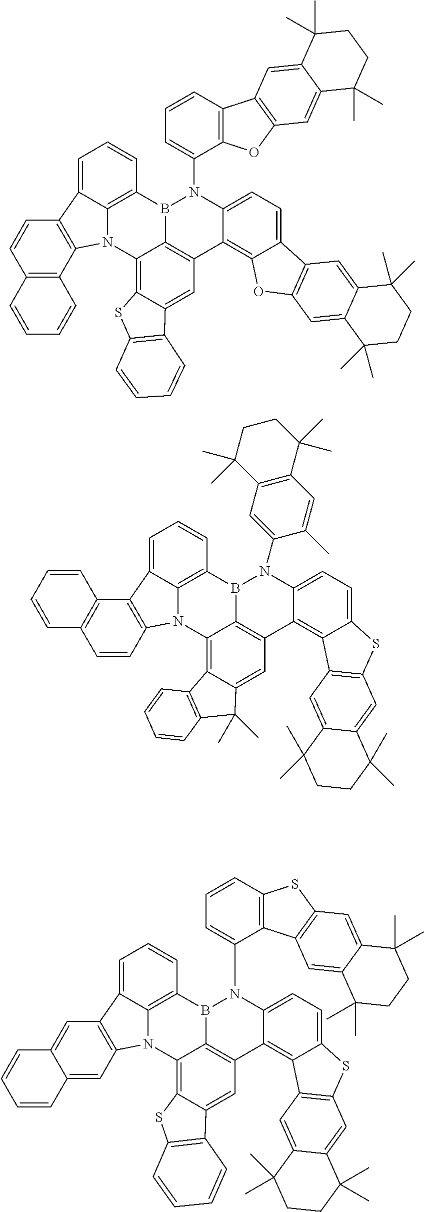 [SMILES: CC1(C)CCC(C)(C)c2cc3c(cc21)oc1c(N2B4c5c(cc6c(sc7ccccc76)c5-n5c6c4cccc6c4ccc6ccccc6c45)-c4c2ccc2c4oc4cc5c(cc42)C(C)(C)CCC5(C)C)cccc13 ; Cc1cc2c(cc1N1B3c4c(cc5c(c4-n4c6ccc7ccccc7c6c6cccc3c64)-c3ccccc3C5(C)C)-c3c1ccc1sc4cc5c(cc4c31)C(C)(C)CCC5(C)C)C(C)(C)CCC2(C)C ; CC1(C)CCC(C)(C)c2cc3c(cc21)sc1cccc(N2B4c5c(cc6c(sc7ccccc76)c5-n5c6cc7ccccc7cc6c6cccc4c65)-c4c2ccc2sc5cc6c(cc5c42)C(C)(C)CCC6(C)C)c13] 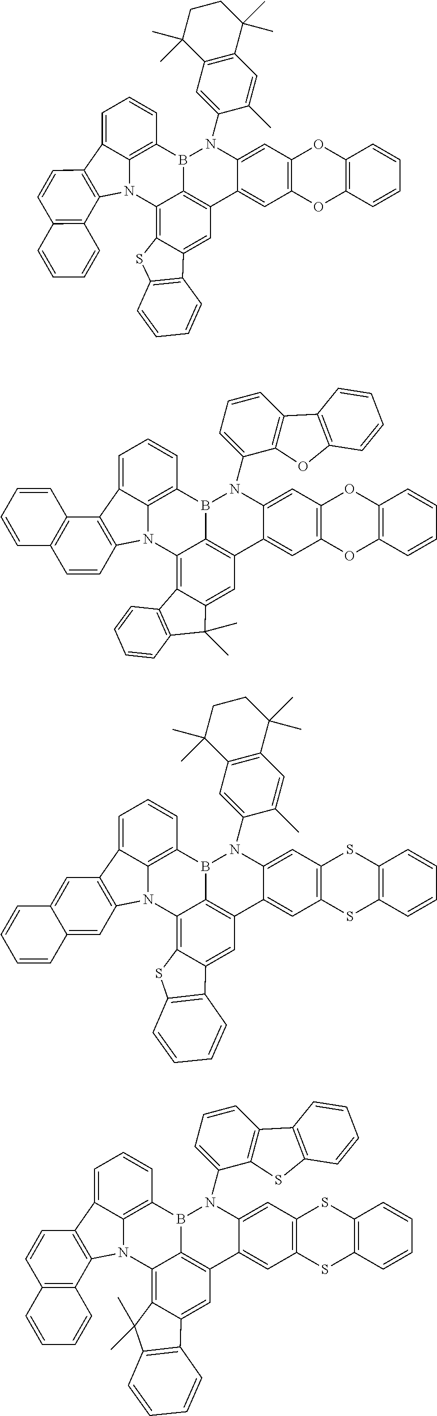 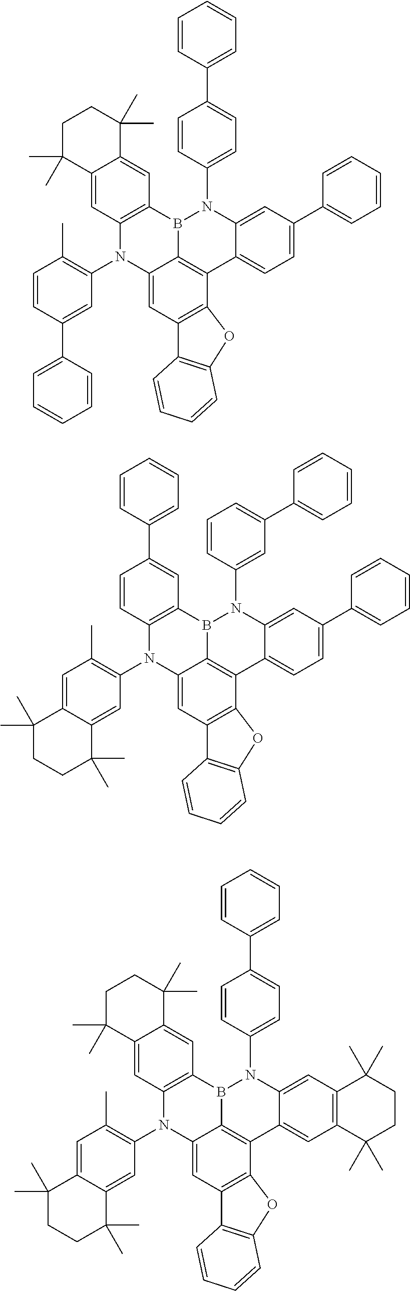 [SMILES: Cc1ccc(-c2ccccc2)cc1N1c2cc3c(cc2B2c4c1cc1c(oc5ccccc51)c4-c1ccc(-c4ccccc4)cc1N2c1ccc(-c2ccccc2)cc1)C(C)(C)CCC3(C)C ; Cc1cc2c(cc1N1c3ccc(-c4ccccc4)cc3B3c4c1cc1c(oc5ccccc51)c4-c1ccc(-c4ccccc4)cc1N3c1cccc(-c3ccccc3)c1)C(C)(C)CCC2(C)C ; Cc1cc2c(cc1N1c3cc4c(cc3B3c5c1cc1c(oc6ccccc61)c5-c1cc5c(cc1N3c1ccc(-c3ccccc3)cc1)C(C)(C)CCC5(C)C)C(C)(C)CCC4(C)C)C(C)(C)CCC2(C)C] 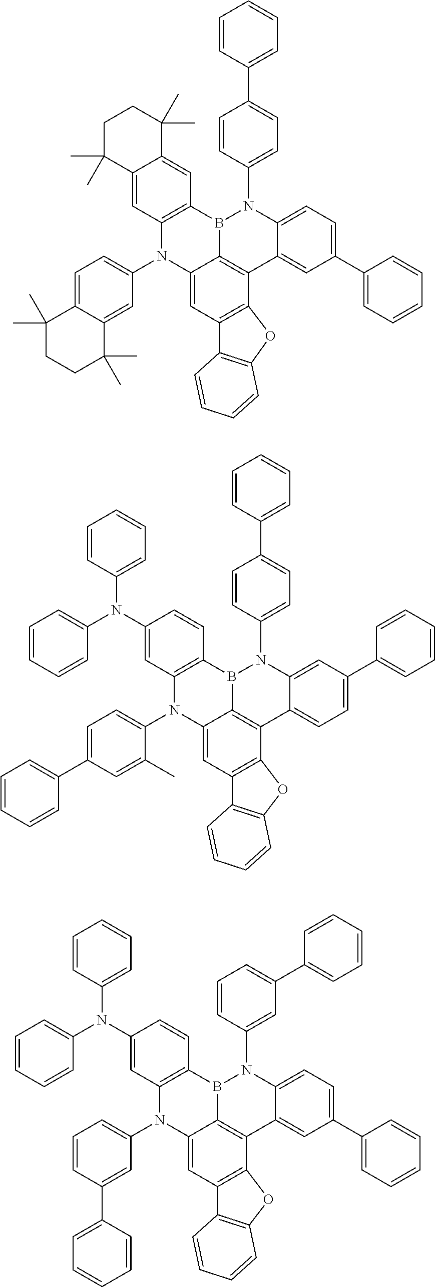 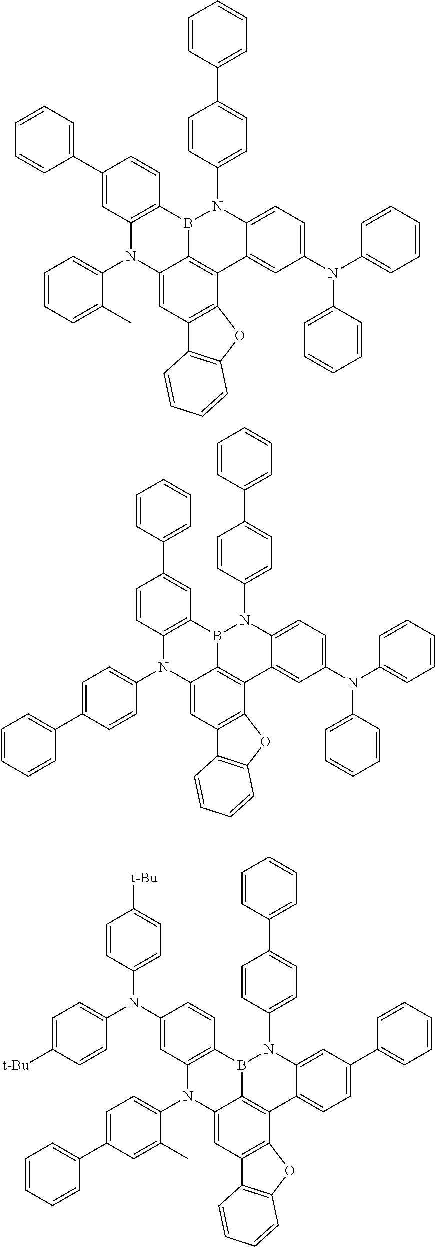 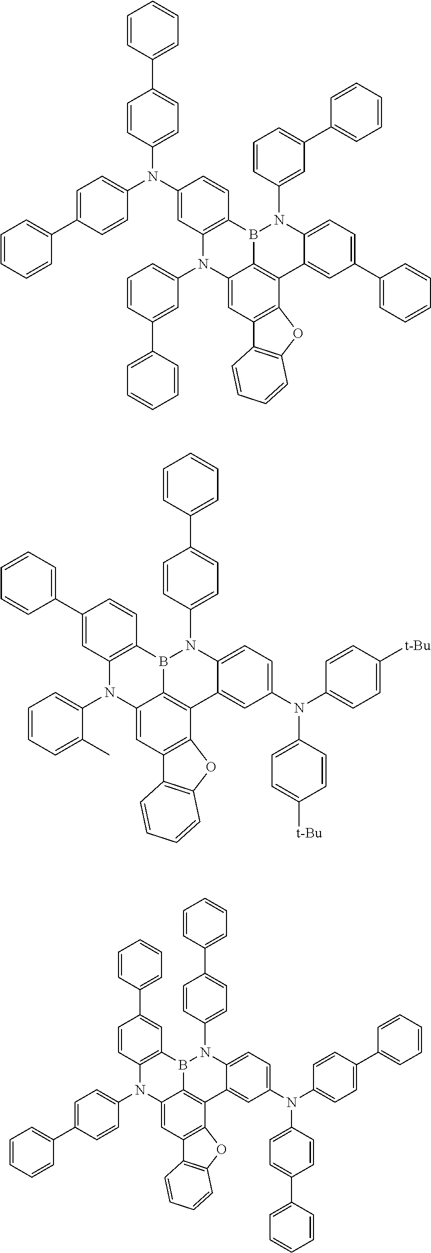 [SMILES: c1ccc(-c2ccc(N(c3ccc(-c4ccccc4)cc3)c3ccc4c(c3)N(c3cccc(-c5ccccc5)c3)c3cc5c(oc6ccccc65)c5c3B4N(c3cccc(-c4ccccc4)c3)c3ccc(-c4ccccc4)cc3-5)cc2)cc1 ; Cc1ccccc1N1c2cc(-c3ccccc3)ccc2B2c3c1cc1c(oc4ccccc41)c3-c1cc(N(c3ccc(C(C)(C)C)cc3)c3ccc(C(C)(C)C)cc3)ccc1N2c1ccc(-c2ccccc2)cc1 ; c1ccc(-c2ccc(N3B4c5cc(-c6ccccc6)ccc5N(c5ccc(-c6ccccc6)cc5)c5cc6c(oc7ccccc76)c(c54)-c4cc(N(c5ccc(-c6ccccc6)cc5)c5ccc(-c6ccccc6)cc5)ccc43)cc2)cc1] 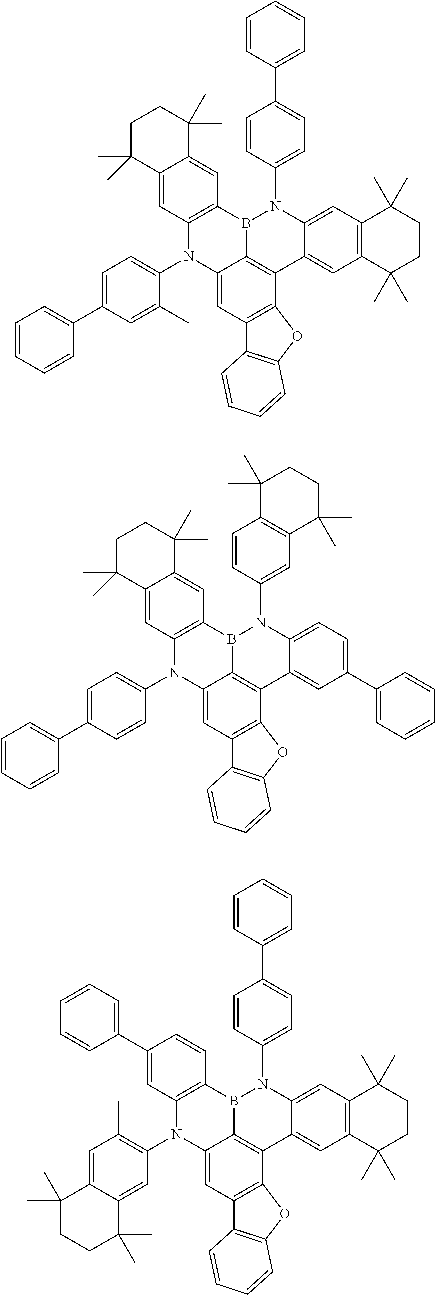 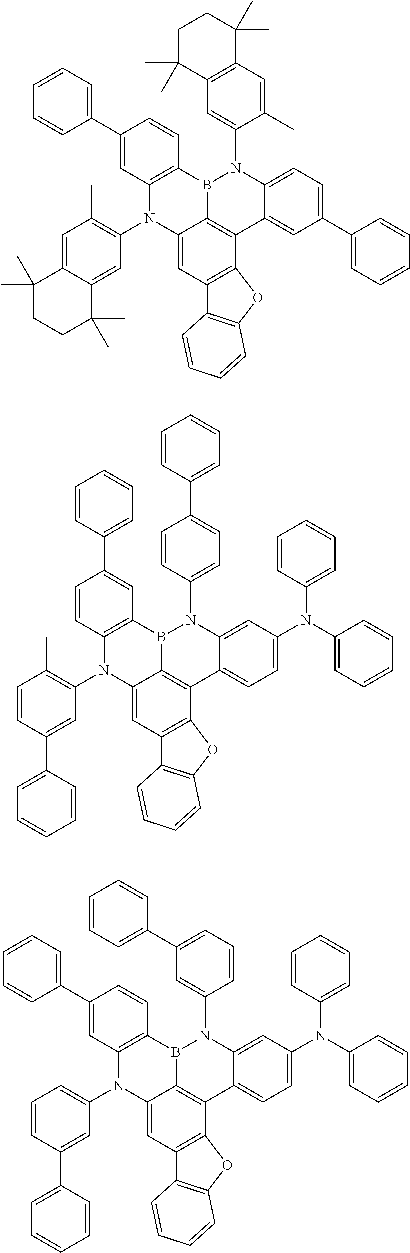 [SMILES: Cc1cc2c(cc1N1B3c4ccc(-c5ccccc5)cc4N(c4cc5c(cc4C)C(C)(C)CCC5(C)C)c4cc5c(oc6ccccc65)c(c43)-c3cc(-c4ccccc4)ccc31)C(C)(C)CCC2(C)C ; Cc1ccc(-c2ccccc2)cc1N1c2ccc(-c3ccccc3)cc2B2c3c1cc1c(oc4ccccc41)c3-c1ccc(N(c3ccccc3)c3ccccc3)cc1N2c1ccc(-c2ccccc2)cc1 ; c1ccc(-c2cccc(N3B4c5ccc(-c6ccccc6)cc5N(c5cccc(-c6ccccc6)c5)c5cc6c(oc7ccccc76)c(c54)-c4ccc(N(c5ccccc5)c5ccccc5)cc43)c2)cc1] 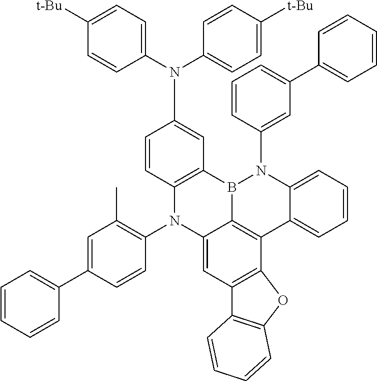 [SMILES: Cc1cc(-c2ccccc2)ccc1N1c2ccc(N(c3ccc(C(C)(C)C)cc3)c3ccc(C(C)(C)C)cc3)cc2B2c3c1cc1c(oc4ccccc41)c3-c1ccccc1N2c1cccc(-c2ccccc2)c1] 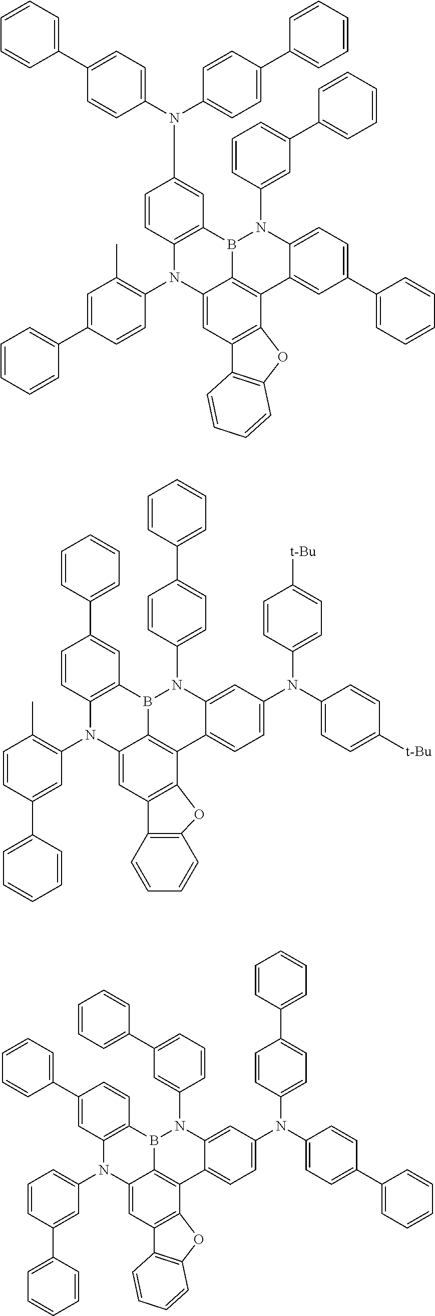 [SMILES: Cc1cc(-c2ccccc2)ccc1N1c2ccc(N(c3ccc(-c4ccccc4)cc3)c3ccc(-c4ccccc4)cc3)cc2B2c3c1cc1c(oc4ccccc41)c3-c1cc(-c3ccccc3)ccc1N2c1cccc(-c2ccccc2)c1 ; Cc1ccc(-c2ccccc2)cc1N1c2ccc(-c3ccccc3)cc2B2c3c1cc1c(oc4ccccc41)c3-c1ccc(N(c3ccc(C(C)(C)C)cc3)c3ccc(C(C)(C)C)cc3)cc1N2c1ccc(-c2ccccc2)cc1 ; c1ccc(-c2ccc(N(c3ccc(-c4ccccc4)cc3)c3ccc4c(c3)N(c3cccc(-c5ccccc5)c3)B3c5ccc(-c6ccccc6)cc5N(c5cccc(-c6ccccc6)c5)c5cc6c(oc7ccccc76)c-4c53)cc2)cc1] 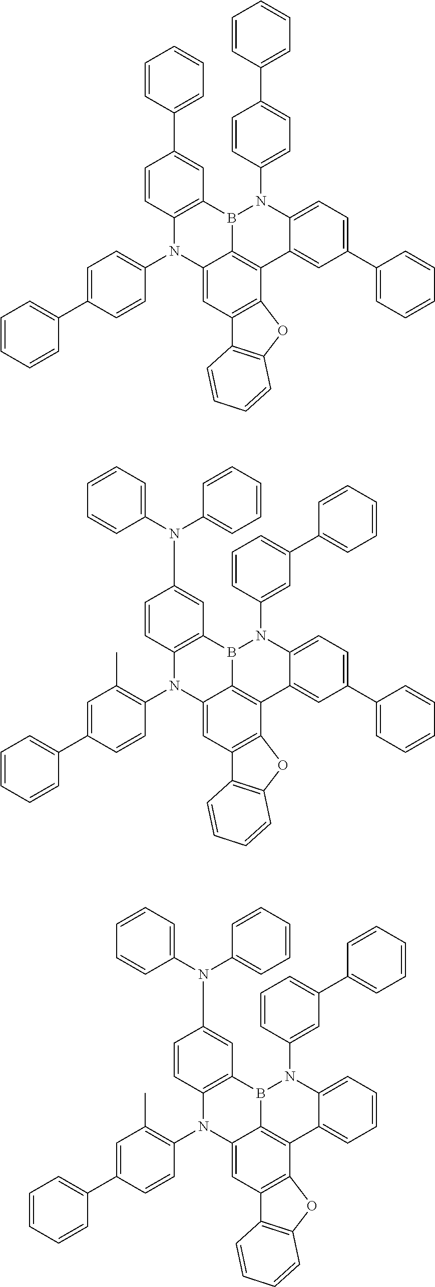 [SMILES: c1ccc(-c2ccc(N3B4c5cc(-c6ccccc6)ccc5N(c5ccc(-c6ccccc6)cc5)c5cc6c(oc7ccccc76)c(c54)-c4cc(-c5ccccc5)ccc43)cc2)cc1 ; Cc1cc(-c2ccccc2)ccc1N1c2ccc(N(c3ccccc3)c3ccccc3)cc2B2c3c1cc1c(oc4ccccc41)c3-c1cc(-c3ccccc3)ccc1N2c1cccc(-c2ccccc2)c1 ; Cc1cc(-c2ccccc2)ccc1N1c2ccc(N(c3ccccc3)c3ccccc3)cc2B2c3c1cc1c(oc4ccccc41)c3-c1ccccc1N2c1cccc(-c2ccccc2)c1] 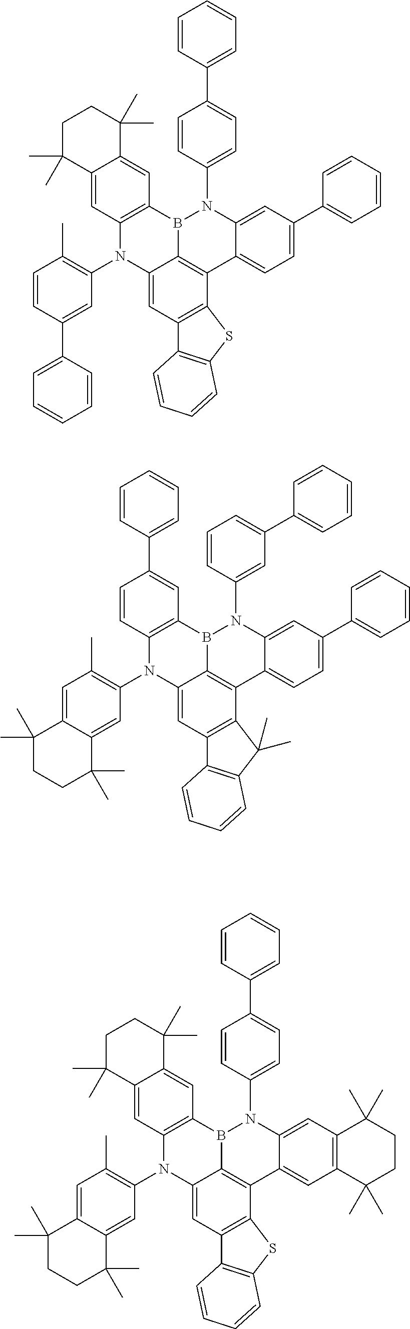 [SMILES: Cc1ccc(-c2ccccc2)cc1N1c2cc3c(cc2B2c4c1cc1c(sc5ccccc51)c4-c1ccc(-c4ccccc4)cc1N2c1ccc(-c2ccccc2)cc1)C(C)(C)CCC3(C)C ; Cc1cc2c(cc1N1c3ccc(-c4ccccc4)cc3B3c4c1cc1c(c4-c4ccc(-c5ccccc5)cc4N3c3cccc(-c4ccccc4)c3)C(C)(C)c3ccccc3-1)C(C)(C)CCC2(C)C ; Cc1cc2c(cc1N1c3cc4c(cc3B3c5c1cc1c(sc6ccccc61)c5-c1cc5c(cc1N3c1ccc(-c3ccccc3)cc1)C(C)(C)CCC5(C)C)C(C)(C)CCC4(C)C)C(C)(C)CCC2(C)C] 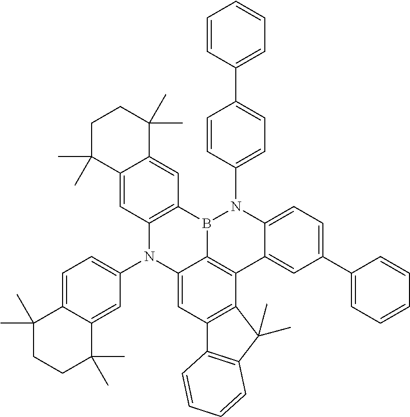 [SMILES: CC1(C)CCC(C)(C)c2cc(N3c4cc5c(cc4B4c6c3cc3c(c6-c6cc(-c7ccccc7)ccc6N4c4ccc(-c6ccccc6)cc4)C(C)(C)c4ccccc4-3)C(C)(C)CCC5(C)C)ccc21] 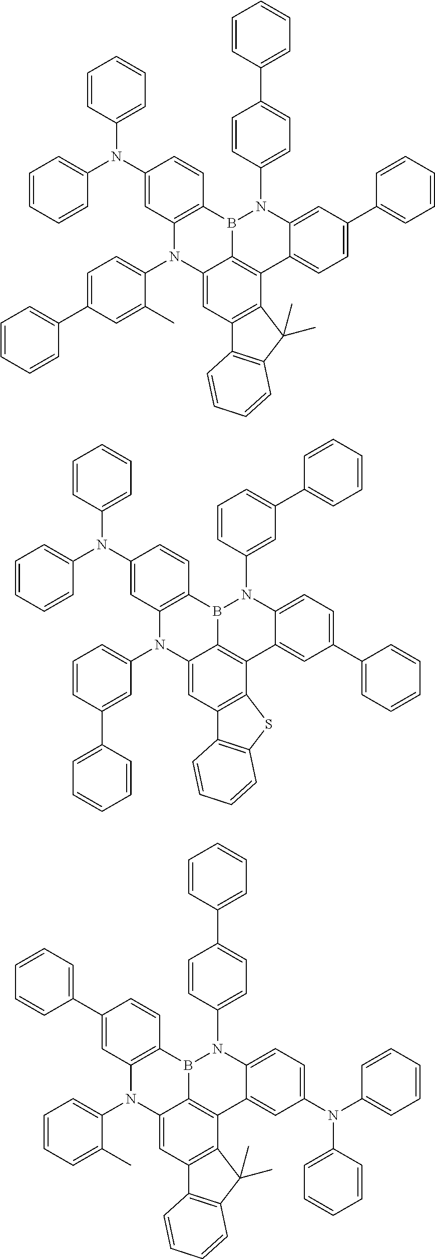 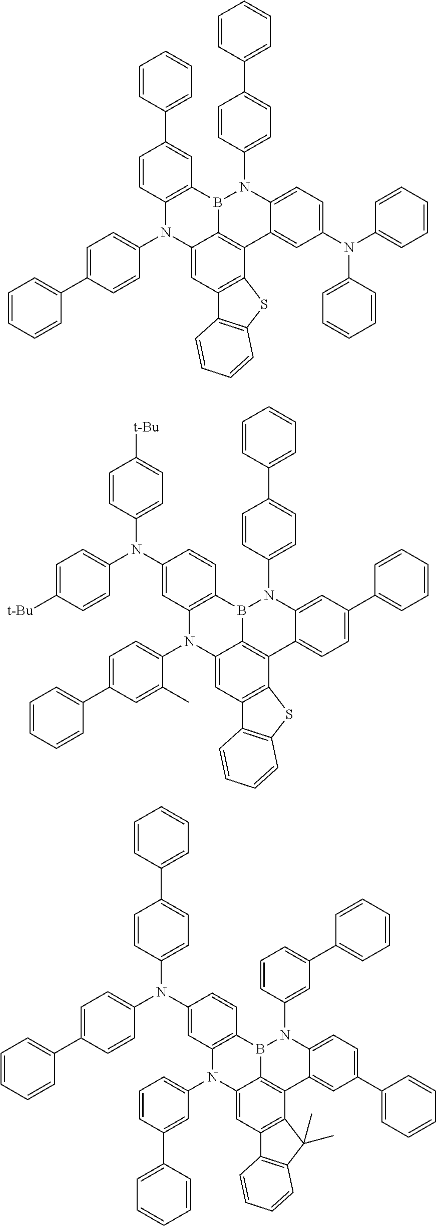 [SMILES: c1ccc(-c2ccc(N3B4c5cc(-c6ccccc6)ccc5N(c5ccc(-c6ccccc6)cc5)c5cc6c(sc7ccccc76)c(c54)-c4cc(N(c5ccccc5)c5ccccc5)ccc43)cc2)cc1 ; Cc1cc(-c2ccccc2)ccc1N1c2cc(N(c3ccc(C(C)(C)C)cc3)c3ccc(C(C)(C)C)cc3)ccc2B2c3c1cc1c(sc4ccccc41)c3-c1ccc(-c3ccccc3)cc1N2c1ccc(-c2ccccc2)cc1 ; CC1(C)c2ccccc2-c2cc3c4c(c21)-c1cc(-c2ccccc2)ccc1N(c1cccc(-c2ccccc2)c1)B4c1ccc(N(c2ccc(-c4ccccc4)cc2)c2ccc(-c4ccccc4)cc2)cc1N3c1cccc(-c2ccccc2)c1] 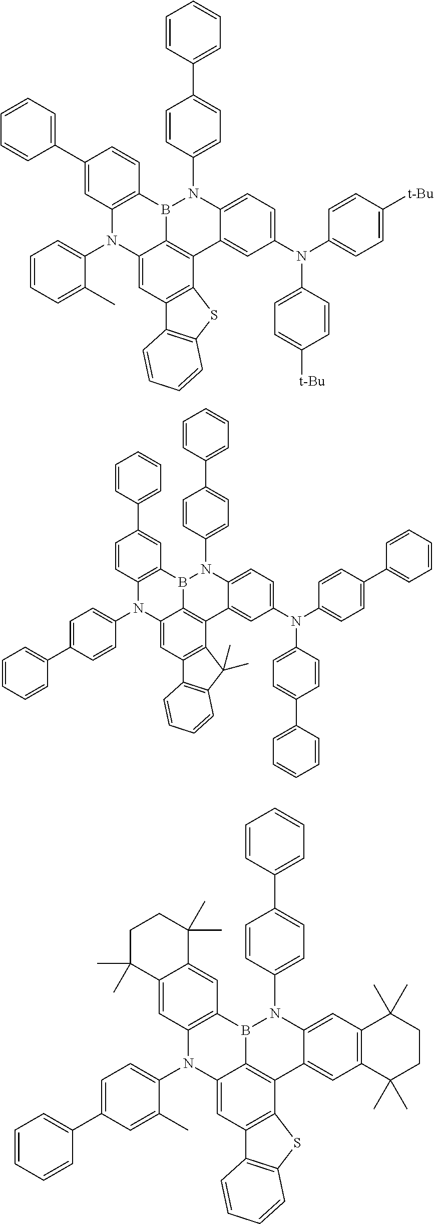 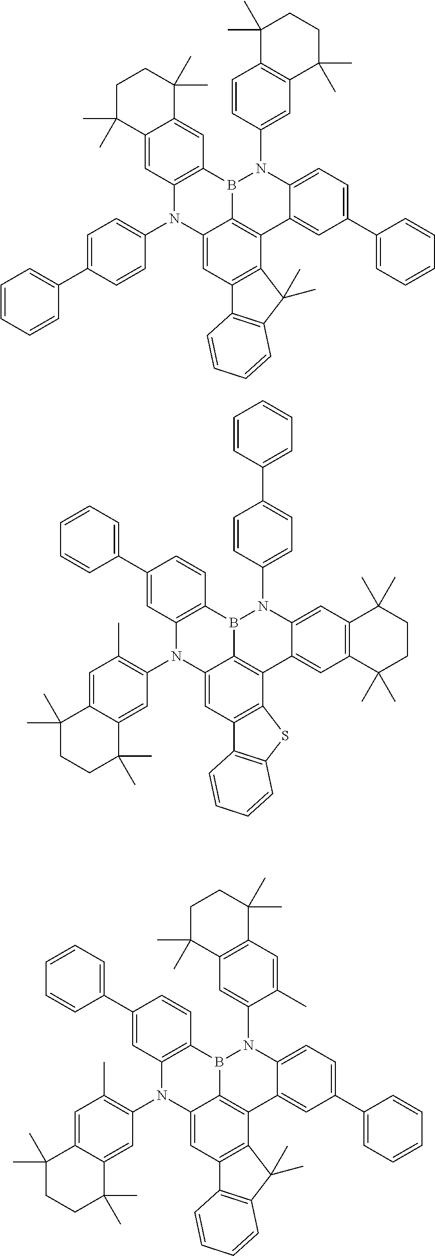 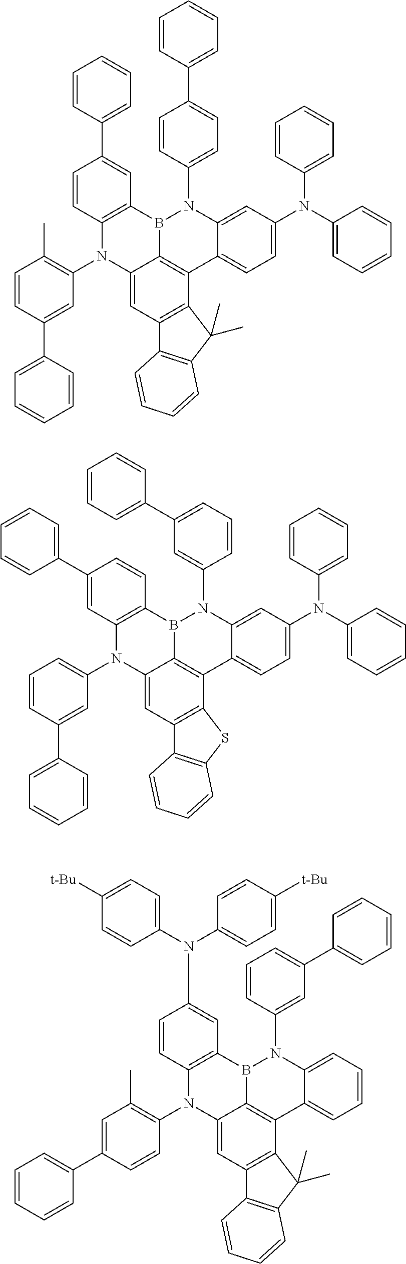 [SMILES: Cc1ccc(-c2ccccc2)cc1N1c2ccc(-c3ccccc3)cc2B2c3c1cc1c(c3-c3ccc(N(c4ccccc4)c4ccccc4)cc3N2c2ccc(-c3ccccc3)cc2)C(C)(C)c2ccccc2-1 ; c1ccc(-c2cccc(N3B4c5ccc(-c6ccccc6)cc5N(c5cccc(-c6ccccc6)c5)c5cc6c(sc7ccccc76)c(c54)-c4ccc(N(c5ccccc5)c5ccccc5)cc43)c2)cc1 ; Cc1cc(-c2ccccc2)ccc1N1c2ccc(N(c3ccc(C(C)(C)C)cc3)c3ccc(C(C)(C)C)cc3)cc2B2c3c1cc1c(c3-c3ccccc3N2c2cccc(-c3ccccc3)c2)C(C)(C)c2ccccc2-1] 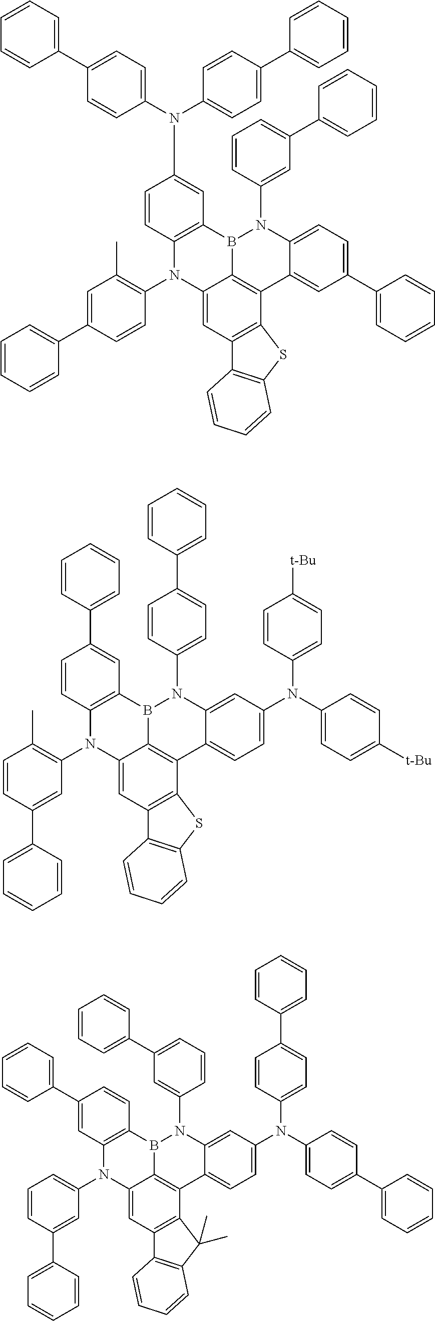 [SMILES: Cc1cc(-c2ccccc2)ccc1N1c2ccc(N(c3ccc(-c4ccccc4)cc3)c3ccc(-c4ccccc4)cc3)cc2B2c3c1cc1c(sc4ccccc41)c3-c1cc(-c3ccccc3)ccc1N2c1cccc(-c2ccccc2)c1 ; Cc1ccc(-c2ccccc2)cc1N1c2ccc(-c3ccccc3)cc2B2c3c1cc1c(sc4ccccc41)c3-c1ccc(N(c3ccc(C(C)(C)C)cc3)c3ccc(C(C)(C)C)cc3)cc1N2c1ccc(-c2ccccc2)cc1 ; CC1(C)c2ccccc2-c2cc3c4c(c21)-c1ccc(N(c2ccc(-c5ccccc5)cc2)c2ccc(-c5ccccc5)cc2)cc1N(c1cccc(-c2ccccc2)c1)B4c1ccc(-c2ccccc2)cc1N3c1cccc(-c2ccccc2)c1] 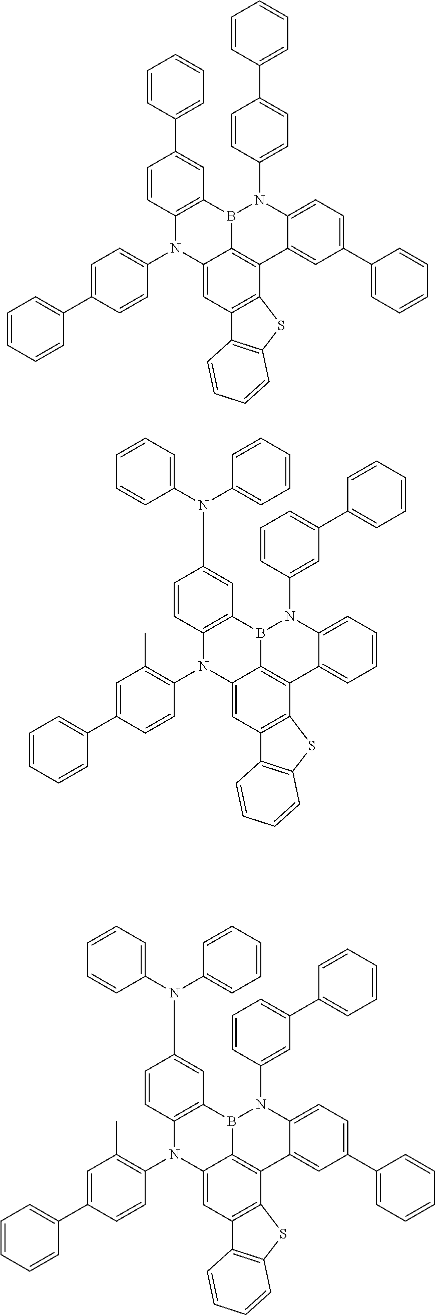 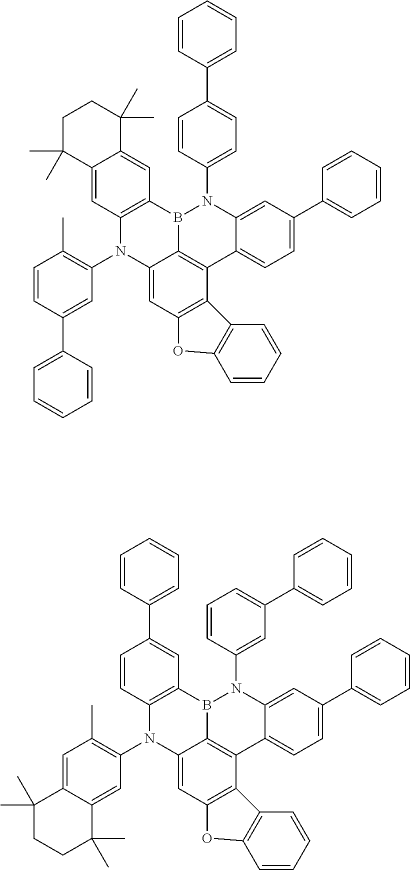 [SMILES: Cc1ccc(-c2ccccc2)cc1N1c2cc3c(cc2B2c4c1cc1oc5ccccc5c1c4-c1ccc(-c4ccccc4)cc1N2c1ccc(-c2ccccc2)cc1)C(C)(C)CCC3(C)C ; Cc1cc2c(cc1N1c3ccc(-c4ccccc4)cc3B3c4c1cc1oc5ccccc5c1c4-c1ccc(-c4ccccc4)cc1N3c1cccc(-c3ccccc3)c1)C(C)(C)CCC2(C)C] 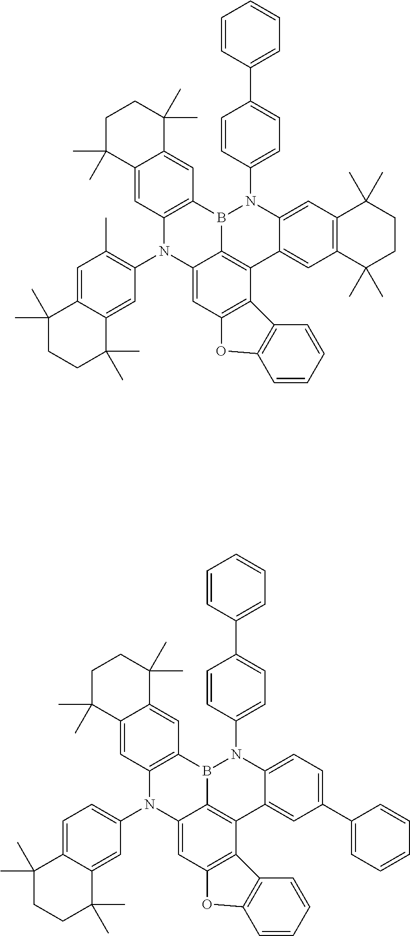 [SMILES: Cc1cc2c(cc1N1c3cc4c(cc3B3c5c1cc1oc6ccccc6c1c5-c1cc5c(cc1N3c1ccc(-c3ccccc3)cc1)C(C)(C)CCC5(C)C)C(C)(C)CCC4(C)C)C(C)(C)CCC2(C)C ; CC1(C)CCC(C)(C)c2cc(N3c4cc5c(cc4B4c6c3cc3oc7ccccc7c3c6-c3cc(-c6ccccc6)ccc3N4c3ccc(-c4ccccc4)cc3)C(C)(C)CCC5(C)C)ccc21] 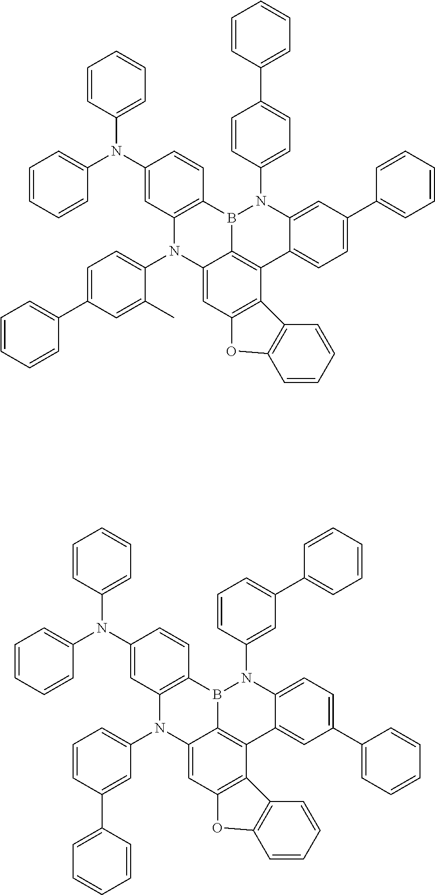 [SMILES: Cc1cc(-c2ccccc2)ccc1N1c2cc(N(c3ccccc3)c3ccccc3)ccc2B2c3c1cc1oc4ccccc4c1c3-c1ccc(-c3ccccc3)cc1N2c1ccc(-c2ccccc2)cc1 ; c1ccc(-c2cccc(N3B4c5ccc(N(c6ccccc6)c6ccccc6)cc5N(c5cccc(-c6ccccc6)c5)c5cc6oc7ccccc7c6c(c54)-c4cc(-c5ccccc5)ccc43)c2)cc1] 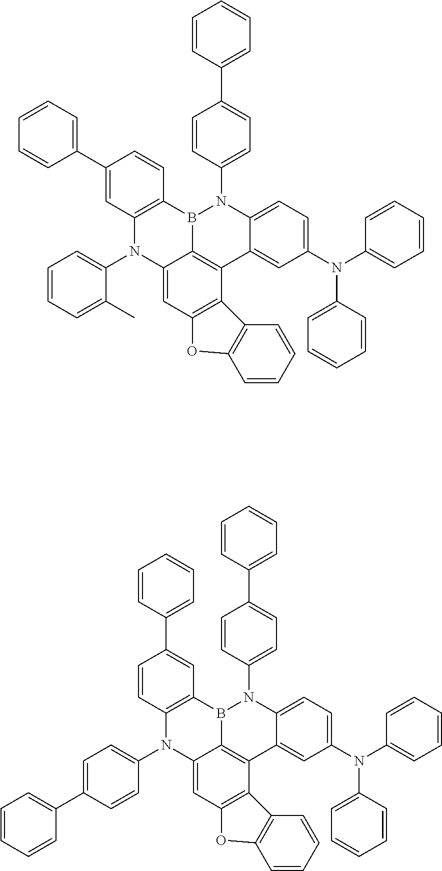 [SMILES: Cc1ccccc1N1c2cc(-c3ccccc3)ccc2B2c3c1cc1oc4ccccc4c1c3-c1cc(N(c3ccccc3)c3ccccc3)ccc1N2c1ccc(-c2ccccc2)cc1 ; c1ccc(-c2ccc(N3B4c5cc(-c6ccccc6)ccc5N(c5ccc(-c6ccccc6)cc5)c5cc6oc7ccccc7c6c(c54)-c4cc(N(c5ccccc5)c5ccccc5)ccc43)cc2)cc1] 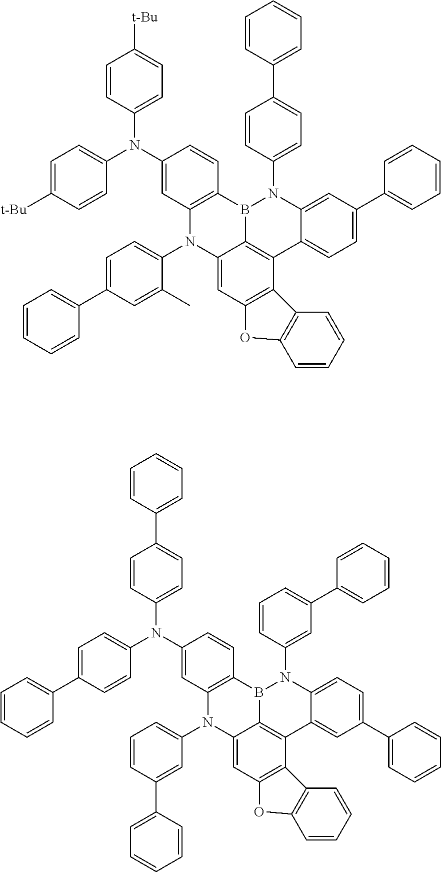 [SMILES: Cc1cc(-c2ccccc2)ccc1N1c2cc(N(c3ccc(C(C)(C)C)cc3)c3ccc(C(C)(C)C)cc3)ccc2B2c3c1cc1oc4ccccc4c1c3-c1ccc(-c3ccccc3)cc1N2c1ccc(-c2ccccc2)cc1 ; c1ccc(-c2ccc(N(c3ccc(-c4ccccc4)cc3)c3ccc4c(c3)N(c3cccc(-c5ccccc5)c3)c3cc5oc6ccccc6c5c5c3B4N(c3cccc(-c4ccccc4)c3)c3ccc(-c4ccccc4)cc3-5)cc2)cc1] 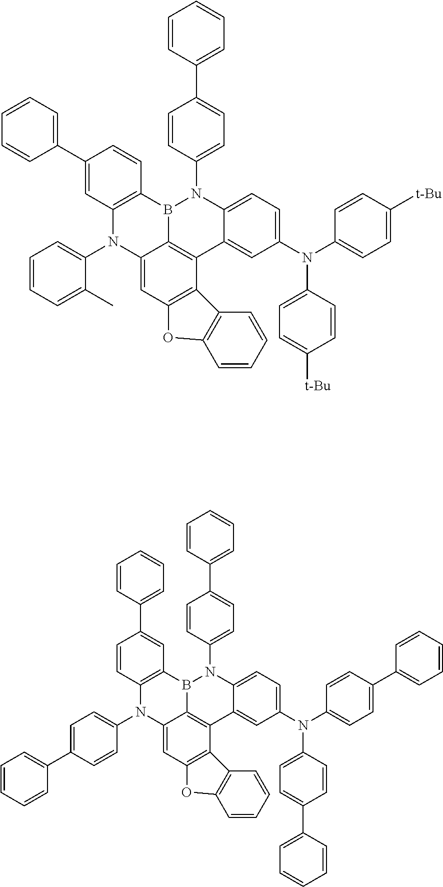 [SMILES: Cc1ccccc1N1c2cc(-c3ccccc3)ccc2B2c3c1cc1oc4ccccc4c1c3-c1cc(N(c3ccc(C(C)(C)C)cc3)c3ccc(C(C)(C)C)cc3)ccc1N2c1ccc(-c2ccccc2)cc1 ; c1ccc(-c2ccc(N3B4c5cc(-c6ccccc6)ccc5N(c5ccc(-c6ccccc6)cc5)c5cc6oc7ccccc7c6c(c54)-c4cc(N(c5ccc(-c6ccccc6)cc5)c5ccc(-c6ccccc6)cc5)ccc43)cc2)cc1] 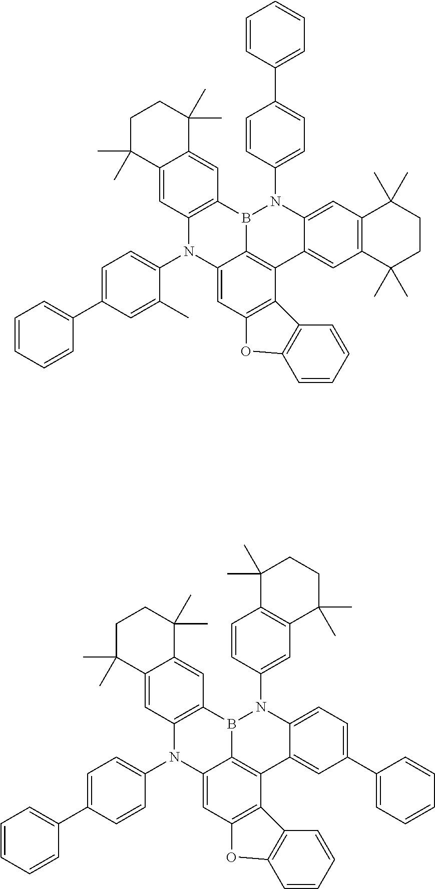 [SMILES: Cc1cc(-c2ccccc2)ccc1N1c2cc3c(cc2B2c4c1cc1oc5ccccc5c1c4-c1cc4c(cc1N2c1ccc(-c2ccccc2)cc1)C(C)(C)CCC4(C)C)C(C)(C)CCC3(C)C ; CC1(C)CCC(C)(C)c2cc(N3B4c5cc6c(cc5N(c5ccc(-c7ccccc7)cc5)c5cc7oc8ccccc8c7c(c54)-c4cc(-c5ccccc5)ccc43)C(C)(C)CCC6(C)C)ccc21] 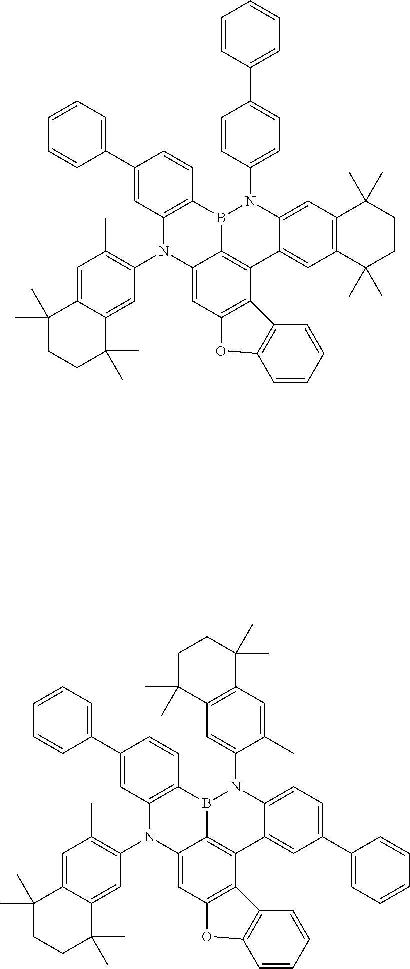 [SMILES: Cc1cc2c(cc1N1c3cc(-c4ccccc4)ccc3B3c4c1cc1oc5ccccc5c1c4-c1cc4c(cc1N3c1ccc(-c3ccccc3)cc1)C(C)(C)CCC4(C)C)C(C)(C)CCC2(C)C ; Cc1cc2c(cc1N1B3c4ccc(-c5ccccc5)cc4N(c4cc5c(cc4C)C(C)(C)CCC5(C)C)c4cc5oc6ccccc6c5c(c43)-c3cc(-c4ccccc4)ccc31)C(C)(C)CCC2(C)C] 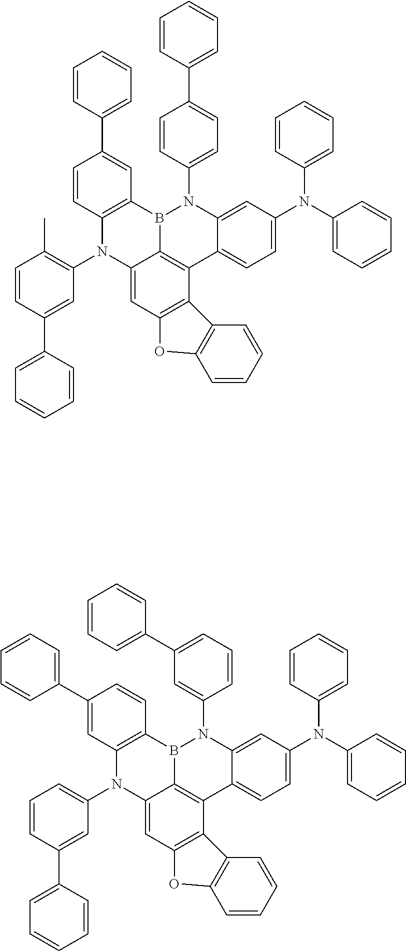 [SMILES: Cc1ccc(-c2ccccc2)cc1N1c2ccc(-c3ccccc3)cc2B2c3c1cc1oc4ccccc4c1c3-c1ccc(N(c3ccccc3)c3ccccc3)cc1N2c1ccc(-c2ccccc2)cc1 ; c1ccc(-c2cccc(N3B4c5ccc(-c6ccccc6)cc5N(c5cccc(-c6ccccc6)c5)c5cc6oc7ccccc7c6c(c54)-c4ccc(N(c5ccccc5)c5ccccc5)cc43)c2)cc1] 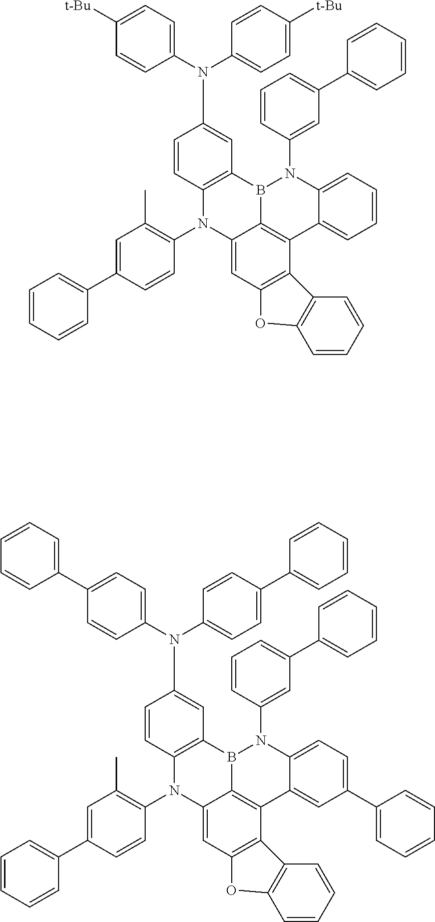 [SMILES: Cc1cc(-c2ccccc2)ccc1N1c2ccc(N(c3ccc(C(C)(C)C)cc3)c3ccc(C(C)(C)C)cc3)cc2B2c3c1cc1oc4ccccc4c1c3-c1ccccc1N2c1cccc(-c2ccccc2)c1 ; Cc1cc(-c2ccccc2)ccc1N1c2ccc(N(c3ccc(-c4ccccc4)cc3)c3ccc(-c4ccccc4)cc3)cc2B2c3c1cc1oc4ccccc4c1c3-c1cc(-c3ccccc3)ccc1N2c1cccc(-c2ccccc2)c1] 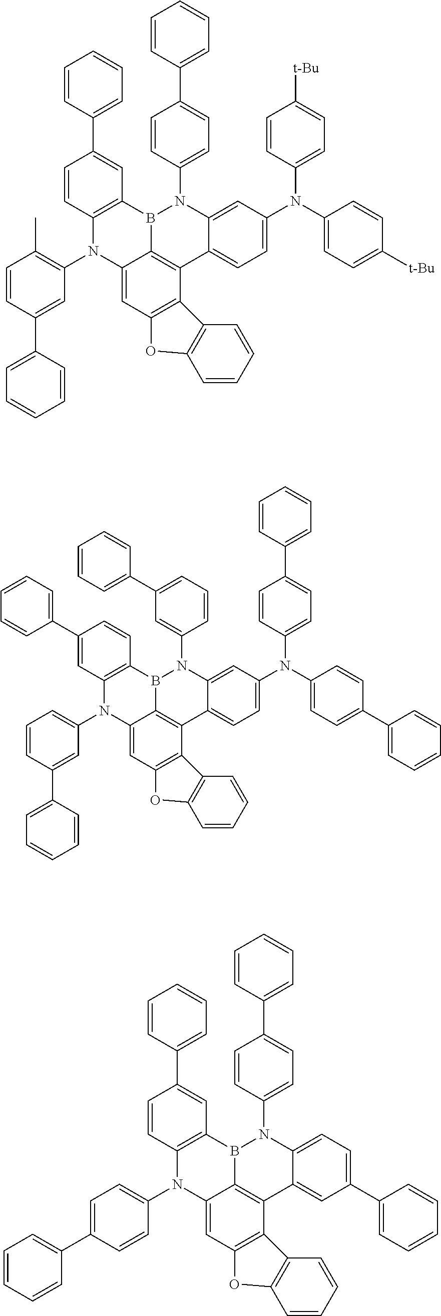 [SMILES: Cc1ccc(-c2ccccc2)cc1N1c2ccc(-c3ccccc3)cc2B2c3c1cc1oc4ccccc4c1c3-c1ccc(N(c3ccc(C(C)(C)C)cc3)c3ccc(C(C)(C)C)cc3)cc1N2c1ccc(-c2ccccc2)cc1 ; c1ccc(-c2ccc(N(c3ccc(-c4ccccc4)cc3)c3ccc4c(c3)N(c3cccc(-c5ccccc5)c3)B3c5ccc(-c6ccccc6)cc5N(c5cccc(-c6ccccc6)c5)c5cc6oc7ccccc7c6c-4c53)cc2)cc1 ; c1ccc(-c2ccc(N3B4c5cc(-c6ccccc6)ccc5N(c5ccc(-c6ccccc6)cc5)c5cc6oc7ccccc7c6c(c54)-c4cc(-c5ccccc5)ccc43)cc2)cc1] 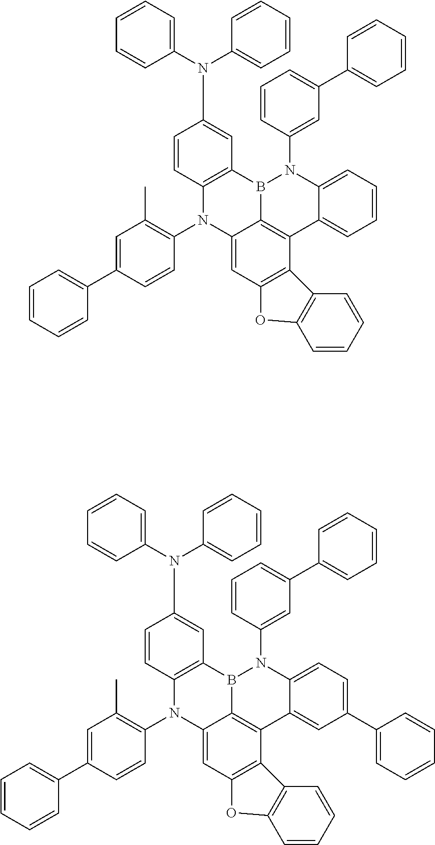 [SMILES: Cc1cc(-c2ccccc2)ccc1N1c2ccc(N(c3ccccc3)c3ccccc3)cc2B2c3c1cc1oc4ccccc4c1c3-c1ccccc1N2c1cccc(-c2ccccc2)c1 ; Cc1cc(-c2ccccc2)ccc1N1c2ccc(N(c3ccccc3)c3ccccc3)cc2B2c3c1cc1oc4ccccc4c1c3-c1cc(-c3ccccc3)ccc1N2c1cccc(-c2ccccc2)c1] 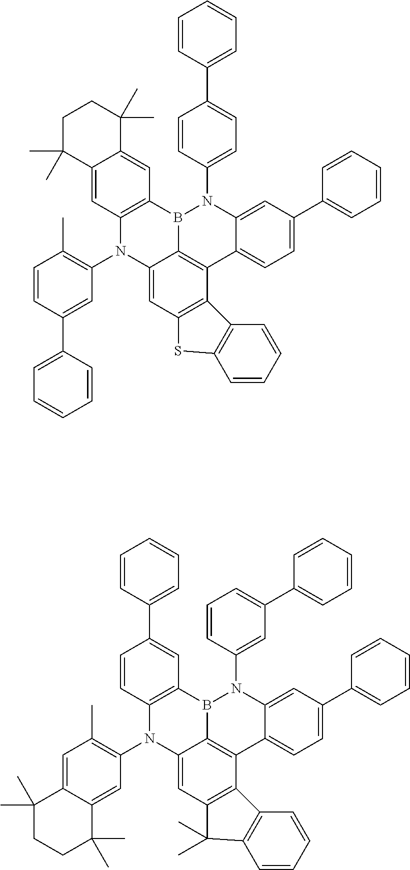 [SMILES: Cc1ccc(-c2ccccc2)cc1N1c2cc3c(cc2B2c4c1cc1sc5ccccc5c1c4-c1ccc(-c4ccccc4)cc1N2c1ccc(-c2ccccc2)cc1)C(C)(C)CCC3(C)C ; Cc1cc2c(cc1N1c3ccc(-c4ccccc4)cc3B3c4c1cc1c(c4-c4ccc(-c5ccccc5)cc4N3c3cccc(-c4ccccc4)c3)-c3ccccc3C1(C)C)C(C)(C)CCC2(C)C] 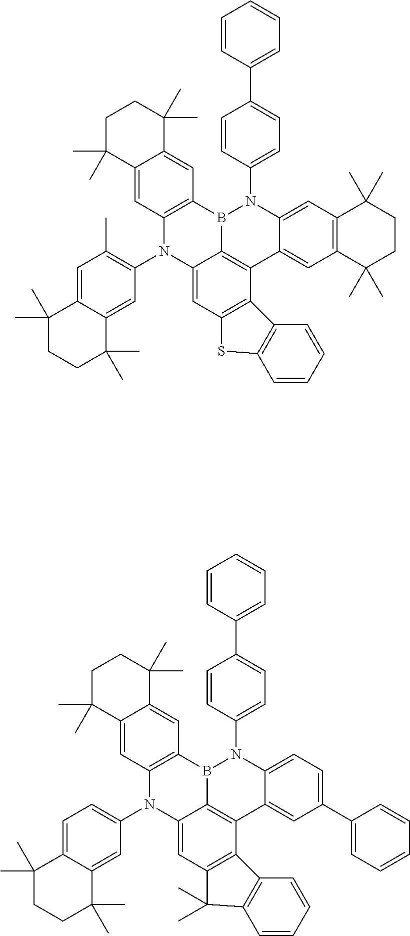 [SMILES: Cc1cc2c(cc1N1c3cc4c(cc3B3c5c1cc1sc6ccccc6c1c5-c1cc5c(cc1N3c1ccc(-c3ccccc3)cc1)C(C)(C)CCC5(C)C)C(C)(C)CCC4(C)C)C(C)(C)CCC2(C)C ; CC1(C)CCC(C)(C)c2cc(N3c4cc5c(cc4B4c6c3cc3c(c6-c6cc(-c7ccccc7)ccc6N4c4ccc(-c6ccccc6)cc4)-c4ccccc4C3(C)C)C(C)(C)CCC5(C)C)ccc21] 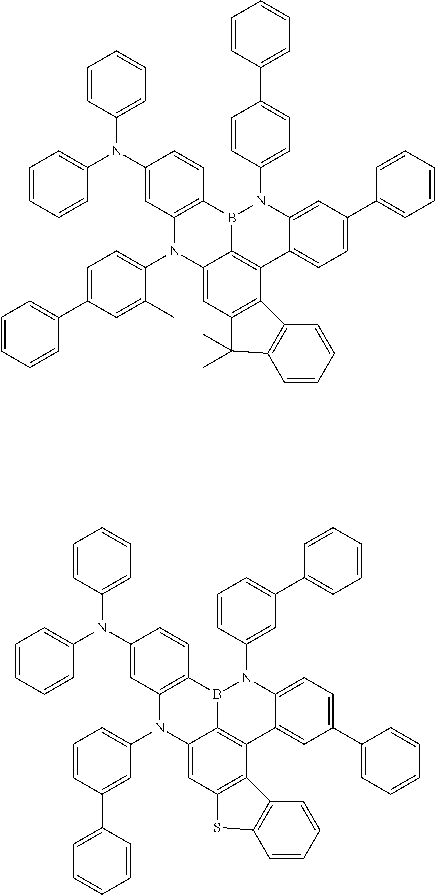 [SMILES: Cc1cc(-c2ccccc2)ccc1N1c2cc(N(c3ccccc3)c3ccccc3)ccc2B2c3c1cc1c(c3-c3ccc(-c4ccccc4)cc3N2c2ccc(-c3ccccc3)cc2)-c2ccccc2C1(C)C ; c1ccc(-c2cccc(N3B4c5ccc(N(c6ccccc6)c6ccccc6)cc5N(c5cccc(-c6ccccc6)c5)c5cc6sc7ccccc7c6c(c54)-c4cc(-c5ccccc5)ccc43)c2)cc1] 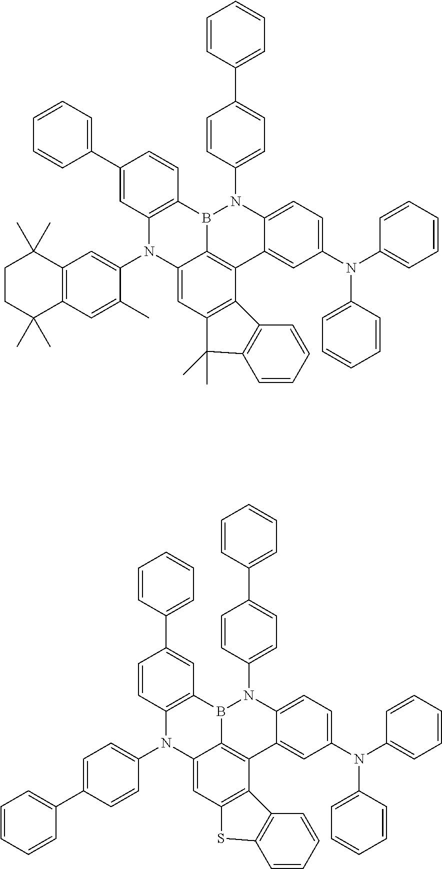 [SMILES: Cc1cc2c(cc1N1c3cc(-c4ccccc4)ccc3B3c4c1cc1c(c4-c4cc(N(c5ccccc5)c5ccccc5)ccc4N3c3ccc(-c4ccccc4)cc3)-c3ccccc3C1(C)C)C(C)(C)CCC2(C)C ; c1ccc(-c2ccc(N3B4c5cc(-c6ccccc6)ccc5N(c5ccc(-c6ccccc6)cc5)c5cc6sc7ccccc7c6c(c54)-c4cc(N(c5ccccc5)c5ccccc5)ccc43)cc2)cc1] 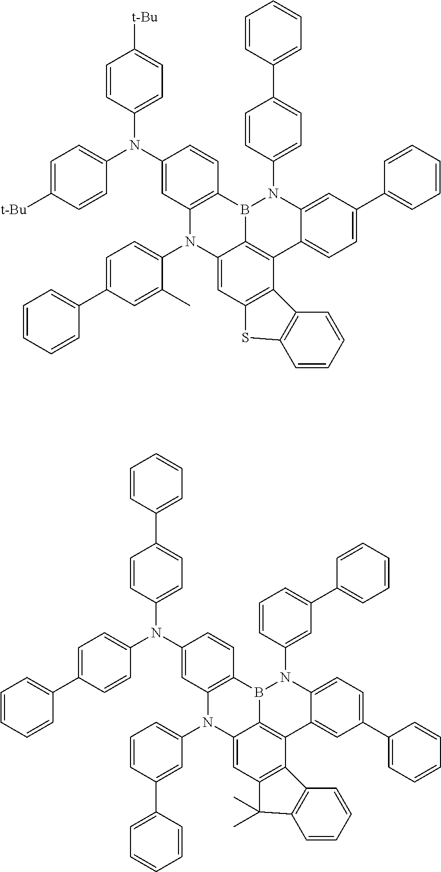 [SMILES: Cc1cc(-c2ccccc2)ccc1N1c2cc(N(c3ccc(C(C)(C)C)cc3)c3ccc(C(C)(C)C)cc3)ccc2B2c3c1cc1sc4ccccc4c1c3-c1ccc(-c3ccccc3)cc1N2c1ccc(-c2ccccc2)cc1 ; CC1(C)c2ccccc2-c2c1cc1c3c2-c2cc(-c4ccccc4)ccc2N(c2cccc(-c4ccccc4)c2)B3c2ccc(N(c3ccc(-c4ccccc4)cc3)c3ccc(-c4ccccc4)cc3)cc2N1c1cccc(-c2ccccc2)c1] 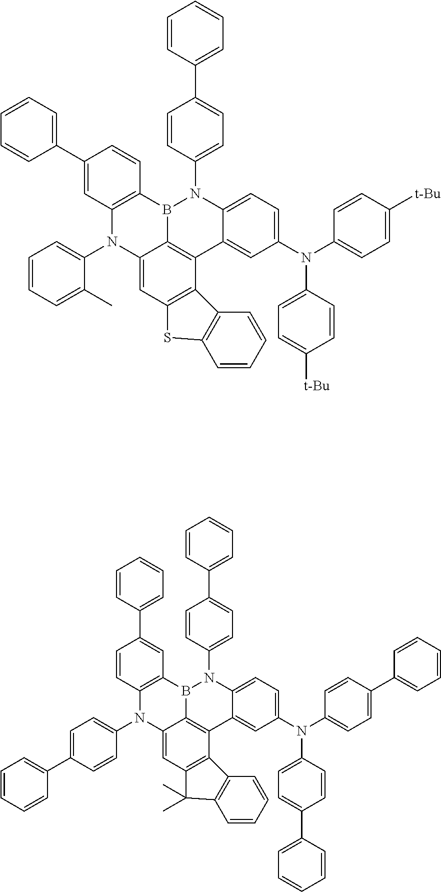 [SMILES: Cc1ccccc1N1c2cc(-c3ccccc3)ccc2B2c3c1cc1sc4ccccc4c1c3-c1cc(N(c3ccc(C(C)(C)C)cc3)c3ccc(C(C)(C)C)cc3)ccc1N2c1ccc(-c2ccccc2)cc1 ; CC1(C)c2ccccc2-c2c1cc1c3c2-c2cc(N(c4ccc(-c5ccccc5)cc4)c4ccc(-c5ccccc5)cc4)ccc2N(c2ccc(-c4ccccc4)cc2)B3c2cc(-c3ccccc3)ccc2N1c1ccc(-c2ccccc2)cc1] 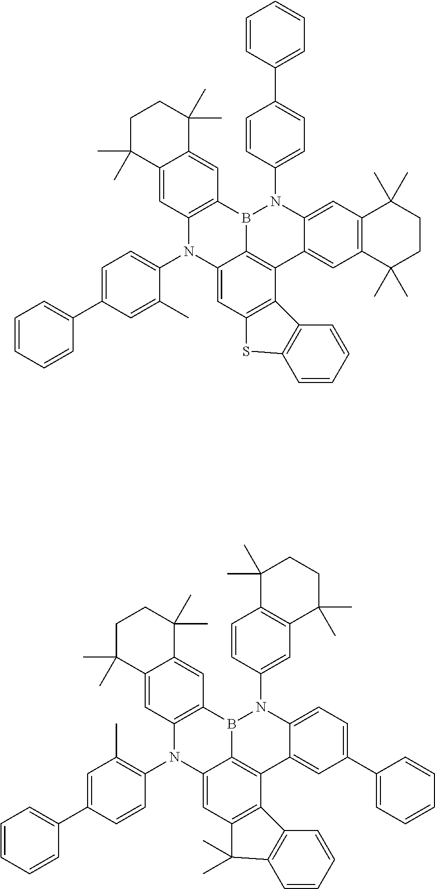 [SMILES: Cc1cc(-c2ccccc2)ccc1N1c2cc3c(cc2B2c4c1cc1sc5ccccc5c1c4-c1cc4c(cc1N2c1ccc(-c2ccccc2)cc1)C(C)(C)CCC4(C)C)C(C)(C)CCC3(C)C ; Cc1cc(-c2ccccc2)ccc1N1c2cc3c(cc2B2c4c1cc1c(c4-c4cc(-c5ccccc5)ccc4N2c2ccc4c(c2)C(C)(C)CCC4(C)C)-c2ccccc2C1(C)C)C(C)(C)CCC3(C)C] 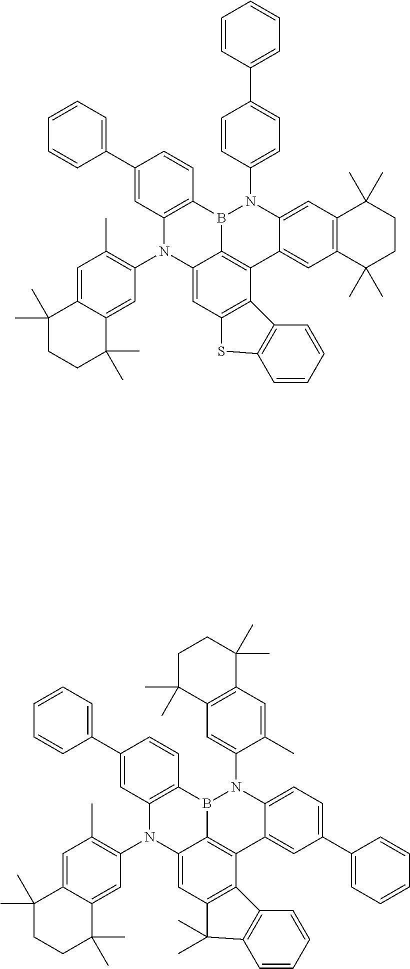 [SMILES: Cc1cc2c(cc1N1c3cc(-c4ccccc4)ccc3B3c4c1cc1sc5ccccc5c1c4-c1cc4c(cc1N3c1ccc(-c3ccccc3)cc1)C(C)(C)CCC4(C)C)C(C)(C)CCC2(C)C ; Cc1cc2c(cc1N1B3c4ccc(-c5ccccc5)cc4N(c4cc5c(cc4C)C(C)(C)CCC5(C)C)c4cc5c(c(c43)-c3cc(-c4ccccc4)ccc31)-c1ccccc1C5(C)C)C(C)(C)CCC2(C)C] 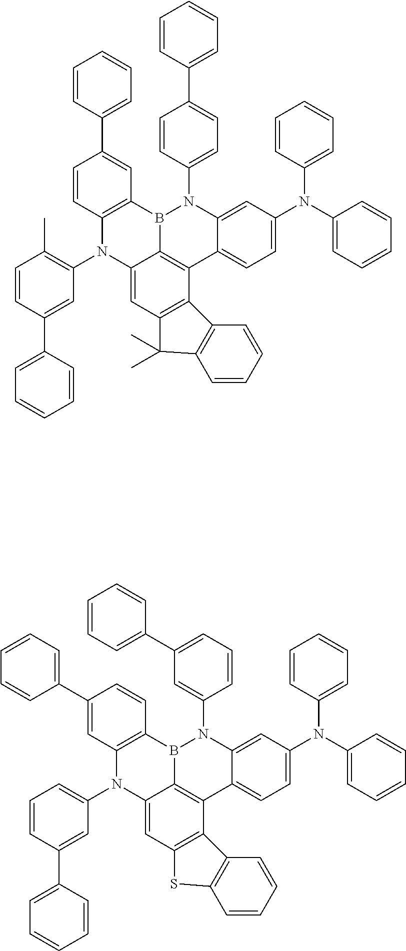 [SMILES: Cc1ccc(-c2ccccc2)cc1N1c2ccc(-c3ccccc3)cc2B2c3c1cc1c(c3-c3ccc(N(c4ccccc4)c4ccccc4)cc3N2c2ccc(-c3ccccc3)cc2)-c2ccccc2C1(C)C ; c1ccc(-c2cccc(N3B4c5ccc(-c6ccccc6)cc5N(c5cccc(-c6ccccc6)c5)c5cc6sc7ccccc7c6c(c54)-c4ccc(N(c5ccccc5)c5ccccc5)cc43)c2)cc1] 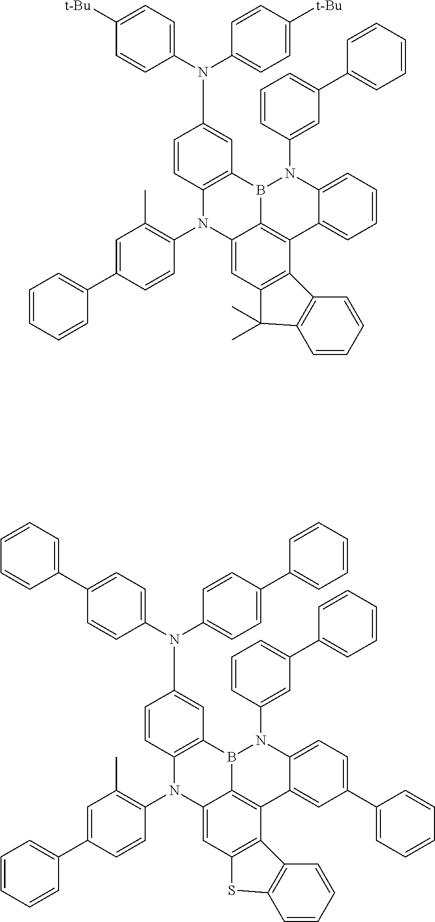 [SMILES: Cc1cc(-c2ccccc2)ccc1N1c2ccc(N(c3ccc(C(C)(C)C)cc3)c3ccc(C(C)(C)C)cc3)cc2B2c3c1cc1c(c3-c3ccccc3N2c2cccc(-c3ccccc3)c2)-c2ccccc2C1(C)C ; Cc1cc(-c2ccccc2)ccc1N1c2ccc(N(c3ccc(-c4ccccc4)cc3)c3ccc(-c4ccccc4)cc3)cc2B2c3c1cc1sc4ccccc4c1c3-c1cc(-c3ccccc3)ccc1N2c1cccc(-c2ccccc2)c1] 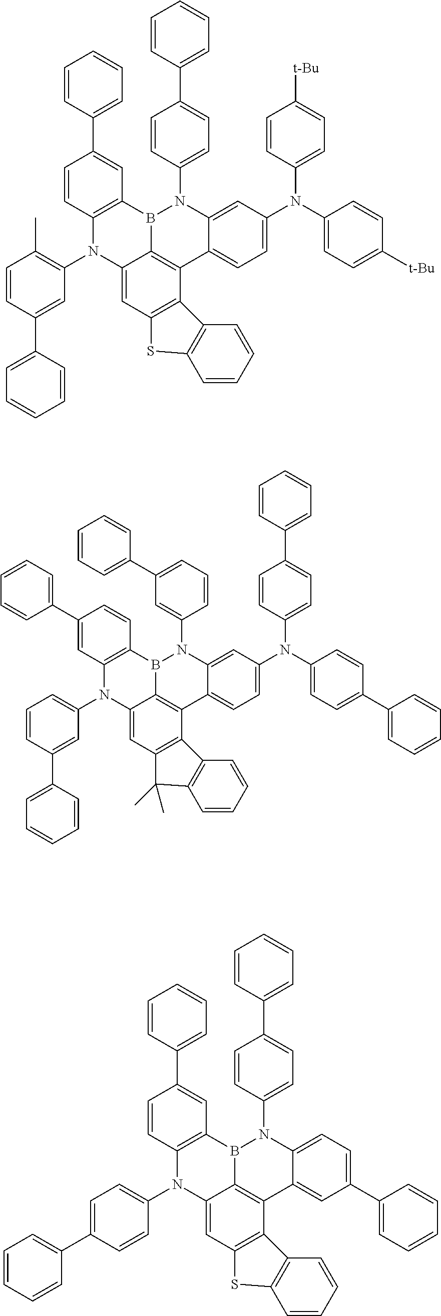 [SMILES: Cc1ccc(-c2ccccc2)cc1N1c2ccc(-c3ccccc3)cc2B2c3c1cc1sc4ccccc4c1c3-c1ccc(N(c3ccc(C(C)(C)C)cc3)c3ccc(C(C)(C)C)cc3)cc1N2c1ccc(-c2ccccc2)cc1 ; CC1(C)c2ccccc2-c2c1cc1c3c2-c2ccc(N(c4ccc(-c5ccccc5)cc4)c4ccc(-c5ccccc5)cc4)cc2N(c2cccc(-c4ccccc4)c2)B3c2ccc(-c3ccccc3)cc2N1c1cccc(-c2ccccc2)c1 ; c1ccc(-c2ccc(N3B4c5cc(-c6ccccc6)ccc5N(c5ccc(-c6ccccc6)cc5)c5cc6sc7ccccc7c6c(c54)-c4cc(-c5ccccc5)ccc43)cc2)cc1] 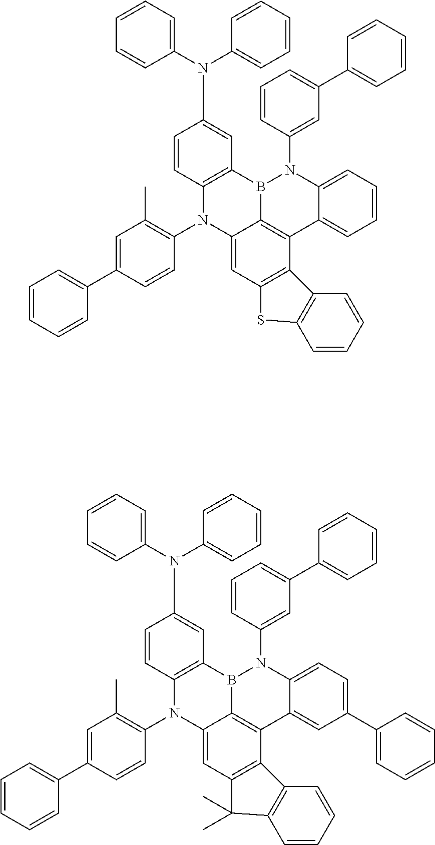 [SMILES: Cc1cc(-c2ccccc2)ccc1N1c2ccc(N(c3ccccc3)c3ccccc3)cc2B2c3c1cc1sc4ccccc4c1c3-c1ccccc1N2c1cccc(-c2ccccc2)c1 ; Cc1cc(-c2ccccc2)ccc1N1c2ccc(N(c3ccccc3)c3ccccc3)cc2B2c3c1cc1c(c3-c3cc(-c4ccccc4)ccc3N2c2cccc(-c3ccccc3)c2)-c2ccccc2C1(C)C] 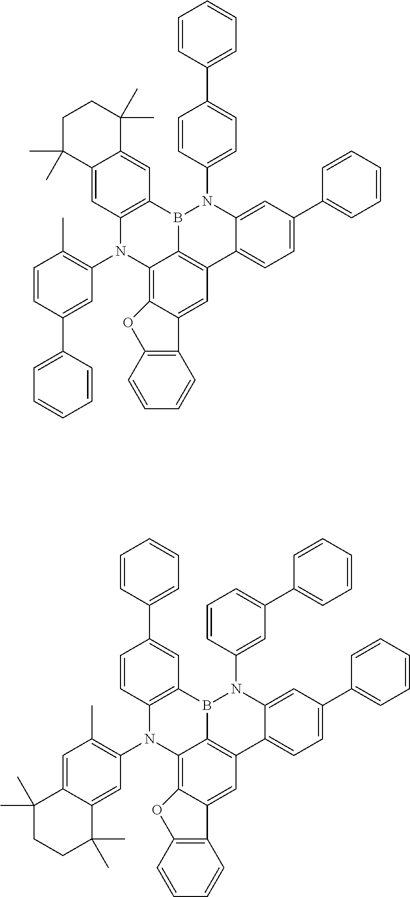 [SMILES: Cc1ccc(-c2ccccc2)cc1N1c2cc3c(cc2B2c4c(cc5c(oc6ccccc65)c41)-c1ccc(-c4ccccc4)cc1N2c1ccc(-c2ccccc2)cc1)C(C)(C)CCC3(C)C ; Cc1cc2c(cc1N1c3ccc(-c4ccccc4)cc3B3c4c(cc5c(oc6ccccc65)c41)-c1ccc(-c4ccccc4)cc1N3c1cccc(-c3ccccc3)c1)C(C)(C)CCC2(C)C] 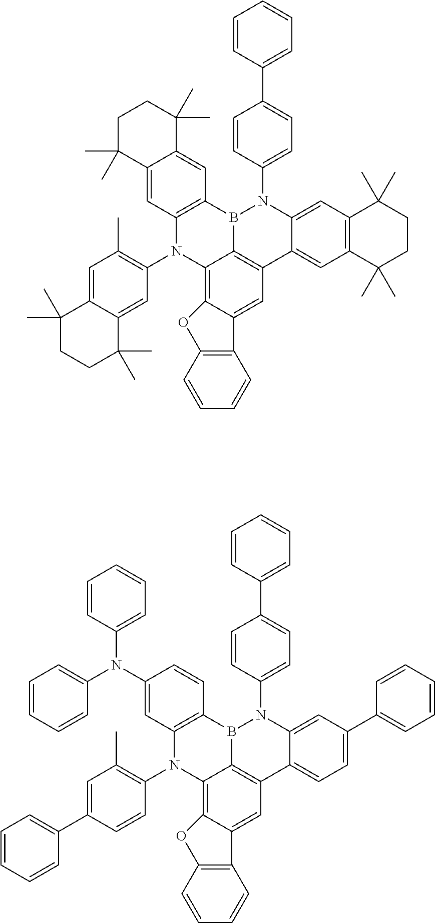 [SMILES: Cc1cc2c(cc1N1c3cc4c(cc3B3c5c(cc6c(oc7ccccc76)c51)-c1cc5c(cc1N3c1ccc(-c3ccccc3)cc1)C(C)(C)CCC5(C)C)C(C)(C)CCC4(C)C)C(C)(C)CCC2(C)C ; Cc1cc(-c2ccccc2)ccc1N1c2cc(N(c3ccccc3)c3ccccc3)ccc2B2c3c(cc4c(oc5ccccc54)c31)-c1ccc(-c3ccccc3)cc1N2c1ccc(-c2ccccc2)cc1] 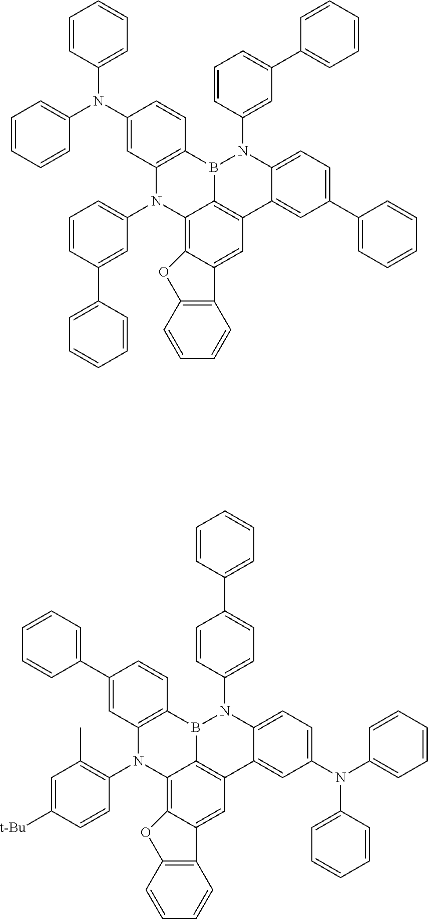 [SMILES: c1ccc(-c2cccc(N3B4c5ccc(N(c6ccccc6)c6ccccc6)cc5N(c5cccc(-c6ccccc6)c5)c5c4c(cc4c5oc5ccccc54)-c4cc(-c5ccccc5)ccc43)c2)cc1 ; Cc1cc(C(C)(C)C)ccc1N1c2cc(-c3ccccc3)ccc2B2c3c(cc4c(oc5ccccc54)c31)-c1cc(N(c3ccccc3)c3ccccc3)ccc1N2c1ccc(-c2ccccc2)cc1] 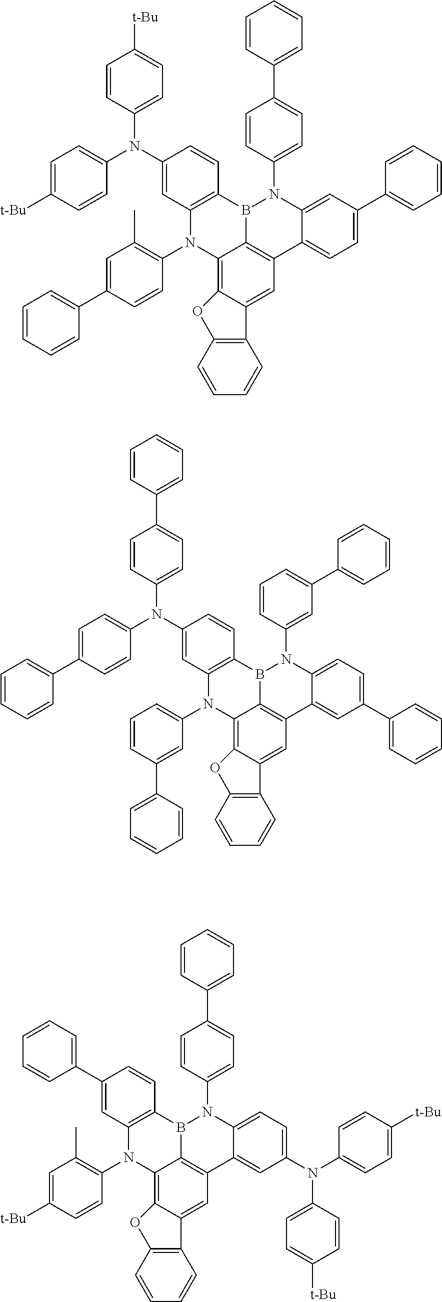 [SMILES: Cc1cc(-c2ccccc2)ccc1N1c2cc(N(c3ccc(C(C)(C)C)cc3)c3ccc(C(C)(C)C)cc3)ccc2B2c3c(cc4c(oc5ccccc54)c31)-c1ccc(-c3ccccc3)cc1N2c1ccc(-c2ccccc2)cc1 ; c1ccc(-c2ccc(N(c3ccc(-c4ccccc4)cc3)c3ccc4c(c3)N(c3cccc(-c5ccccc5)c3)c3c5c(cc6c3oc3ccccc36)-c3cc(-c6ccccc6)ccc3N(c3cccc(-c6ccccc6)c3)B45)cc2)cc1 ; Cc1cc(C(C)(C)C)ccc1N1c2cc(-c3ccccc3)ccc2B2c3c(cc4c(oc5ccccc54)c31)-c1cc(N(c3ccc(C(C)(C)C)cc3)c3ccc(C(C)(C)C)cc3)ccc1N2c1ccc(-c2ccccc2)cc1] 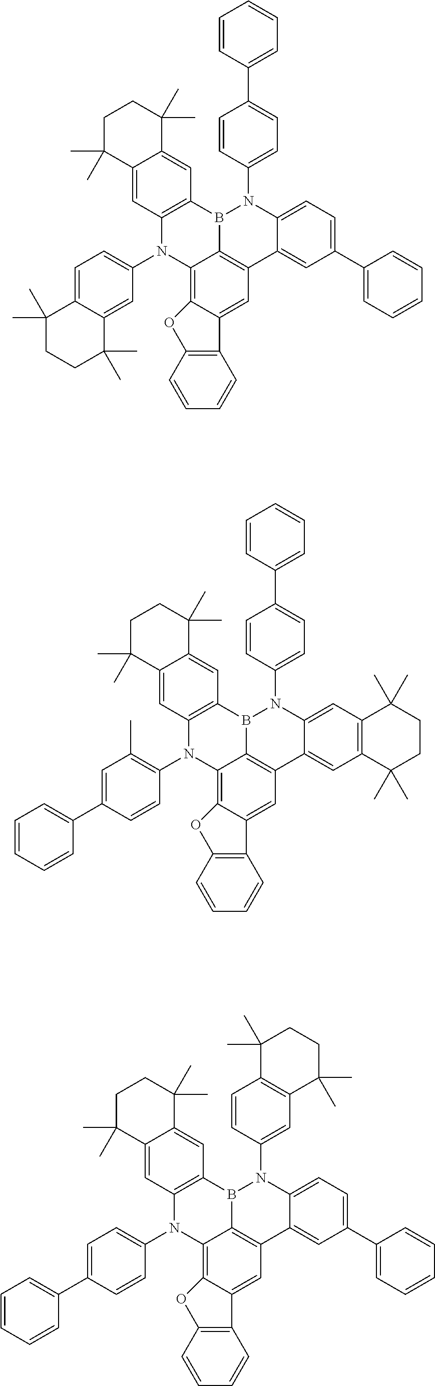 [SMILES: CC1(C)CCC(C)(C)c2cc(N3c4cc5c(cc4B4c6c(cc7c(oc8ccccc87)c63)-c3cc(-c6ccccc6)ccc3N4c3ccc(-c4ccccc4)cc3)C(C)(C)CCC5(C)C)ccc21 ; Cc1cc(-c2ccccc2)ccc1N1c2cc3c(cc2B2c4c(cc5c(oc6ccccc65)c41)-c1cc4c(cc1N2c1ccc(-c2ccccc2)cc1)C(C)(C)CCC4(C)C)C(C)(C)CCC3(C)C ; CC1(C)CCC(C)(C)c2cc(N3B4c5cc6c(cc5N(c5ccc(-c7ccccc7)cc5)c5c4c(cc4c5oc5ccccc54)-c4cc(-c5ccccc5)ccc43)C(C)(C)CCC6(C)C)ccc21] 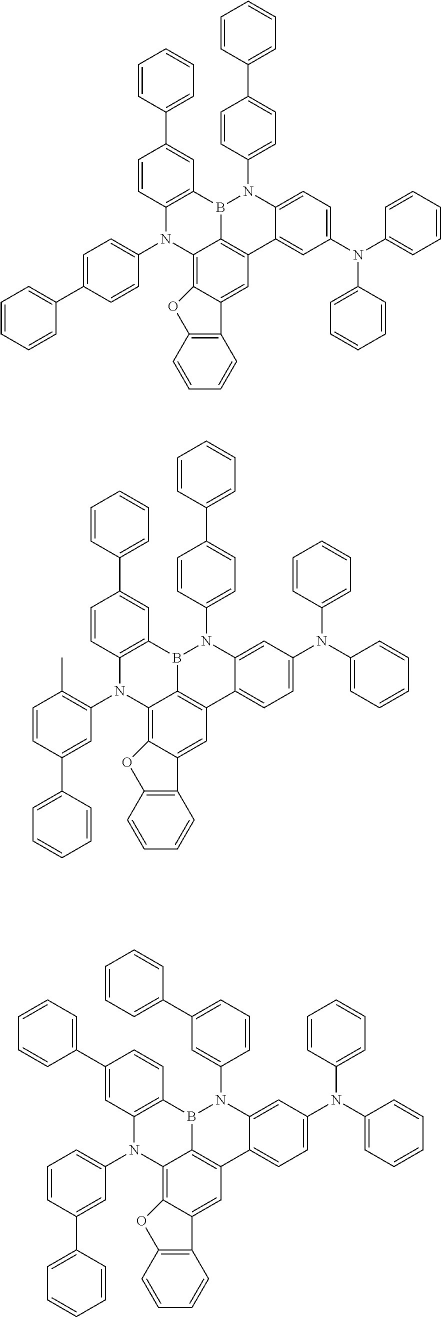 [SMILES: c1ccc(-c2ccc(N3B4c5cc(-c6ccccc6)ccc5N(c5ccc(-c6ccccc6)cc5)c5c4c(cc4c5oc5ccccc54)-c4cc(N(c5ccccc5)c5ccccc5)ccc43)cc2)cc1 ; Cc1ccc(-c2ccccc2)cc1N1c2ccc(-c3ccccc3)cc2B2c3c(cc4c(oc5ccccc54)c31)-c1ccc(N(c3ccccc3)c3ccccc3)cc1N2c1ccc(-c2ccccc2)cc1 ; c1ccc(-c2cccc(N3B4c5ccc(-c6ccccc6)cc5N(c5cccc(-c6ccccc6)c5)c5c4c(cc4c5oc5ccccc54)-c4ccc(N(c5ccccc5)c5ccccc5)cc43)c2)cc1] 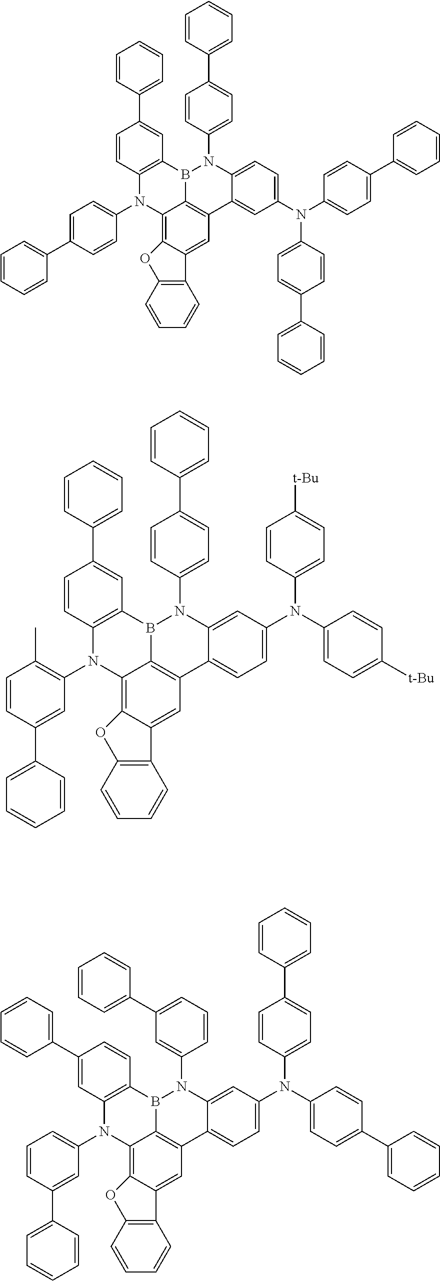 [SMILES: c1ccc(-c2ccc(N3B4c5cc(-c6ccccc6)ccc5N(c5ccc(-c6ccccc6)cc5)c5c4c(cc4c5oc5ccccc54)-c4cc(N(c5ccc(-c6ccccc6)cc5)c5ccc(-c6ccccc6)cc5)ccc43)cc2)cc1 ; Cc1ccc(-c2ccccc2)cc1N1c2ccc(-c3ccccc3)cc2B2c3c(cc4c(oc5ccccc54)c31)-c1ccc(N(c3ccc(C(C)(C)C)cc3)c3ccc(C(C)(C)C)cc3)cc1N2c1ccc(-c2ccccc2)cc1 ; c1ccc(-c2ccc(N(c3ccc(-c4ccccc4)cc3)c3ccc4c(c3)N(c3cccc(-c5ccccc5)c3)B3c5ccc(-c6ccccc6)cc5N(c5cccc(-c6ccccc6)c5)c5c3c-4cc3c5oc4ccccc43)cc2)cc1] 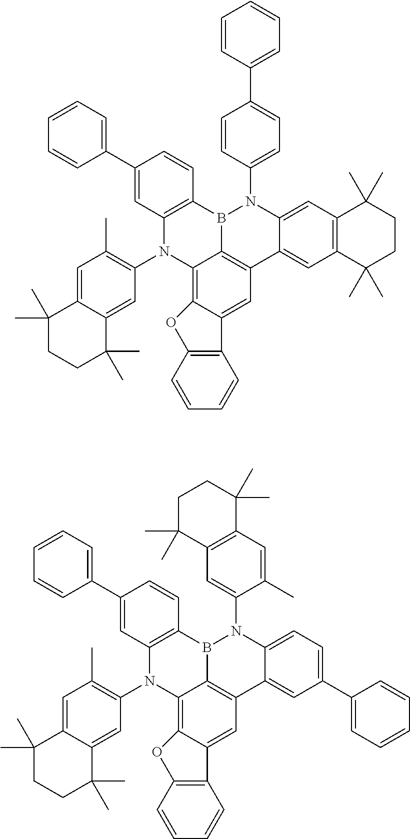 [SMILES: Cc1cc2c(cc1N1c3cc(-c4ccccc4)ccc3B3c4c(cc5c(oc6ccccc65)c41)-c1cc4c(cc1N3c1ccc(-c3ccccc3)cc1)C(C)(C)CCC4(C)C)C(C)(C)CCC2(C)C ; Cc1cc2c(cc1N1B3c4ccc(-c5ccccc5)cc4N(c4cc5c(cc4C)C(C)(C)CCC5(C)C)c4c3c(cc3c4oc4ccccc43)-c3cc(-c4ccccc4)ccc31)C(C)(C)CCC2(C)C] 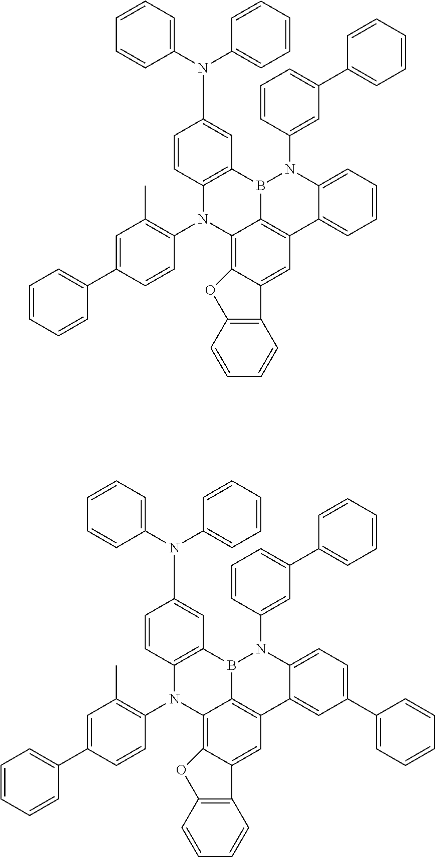 [SMILES: Cc1cc(-c2ccccc2)ccc1N1c2ccc(N(c3ccccc3)c3ccccc3)cc2B2c3c(cc4c(oc5ccccc54)c31)-c1ccccc1N2c1cccc(-c2ccccc2)c1 ; Cc1cc(-c2ccccc2)ccc1N1c2ccc(N(c3ccccc3)c3ccccc3)cc2B2c3c(cc4c(oc5ccccc54)c31)-c1cc(-c3ccccc3)ccc1N2c1cccc(-c2ccccc2)c1] 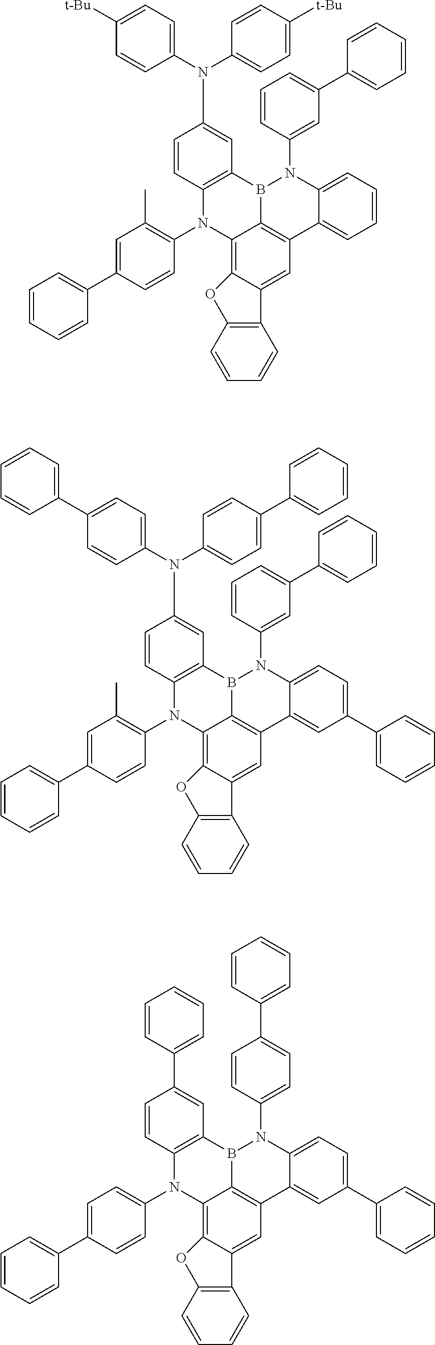 [SMILES: Cc1cc(-c2ccccc2)ccc1N1c2ccc(N(c3ccc(C(C)(C)C)cc3)c3ccc(C(C)(C)C)cc3)cc2B2c3c(cc4c(oc5ccccc54)c31)-c1ccccc1N2c1cccc(-c2ccccc2)c1 ; Cc1cc(-c2ccccc2)ccc1N1c2ccc(N(c3ccc(-c4ccccc4)cc3)c3ccc(-c4ccccc4)cc3)cc2B2c3c(cc4c(oc5ccccc54)c31)-c1cc(-c3ccccc3)ccc1N2c1cccc(-c2ccccc2)c1 ; c1ccc(-c2ccc(N3B4c5cc(-c6ccccc6)ccc5N(c5ccc(-c6ccccc6)cc5)c5c4c(cc4c5oc5ccccc54)-c4cc(-c5ccccc5)ccc43)cc2)cc1] 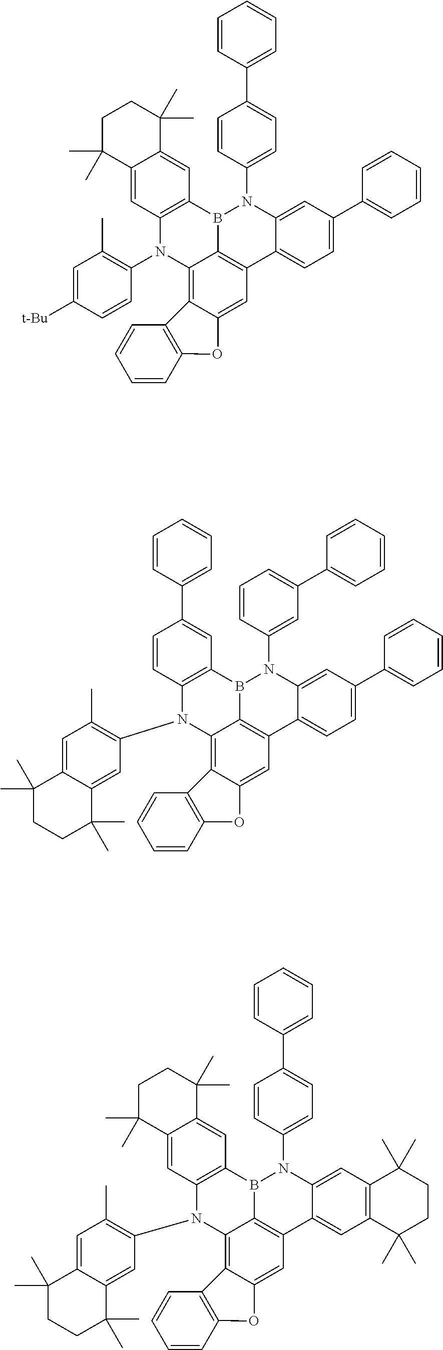 [SMILES: Cc1cc(C(C)(C)C)ccc1N1c2cc3c(cc2B2c4c(cc5oc6ccccc6c5c41)-c1ccc(-c4ccccc4)cc1N2c1ccc(-c2ccccc2)cc1)C(C)(C)CCC3(C)C ; Cc1cc2c(cc1N1c3ccc(-c4ccccc4)cc3B3c4c(cc5oc6ccccc6c5c41)-c1ccc(-c4ccccc4)cc1N3c1cccc(-c3ccccc3)c1)C(C)(C)CCC2(C)C ; Cc1cc2c(cc1N1c3cc4c(cc3B3c5c(cc6oc7ccccc7c6c51)-c1cc5c(cc1N3c1ccc(-c3ccccc3)cc1)C(C)(C)CCC5(C)C)C(C)(C)CCC4(C)C)C(C)(C)CCC2(C)C] 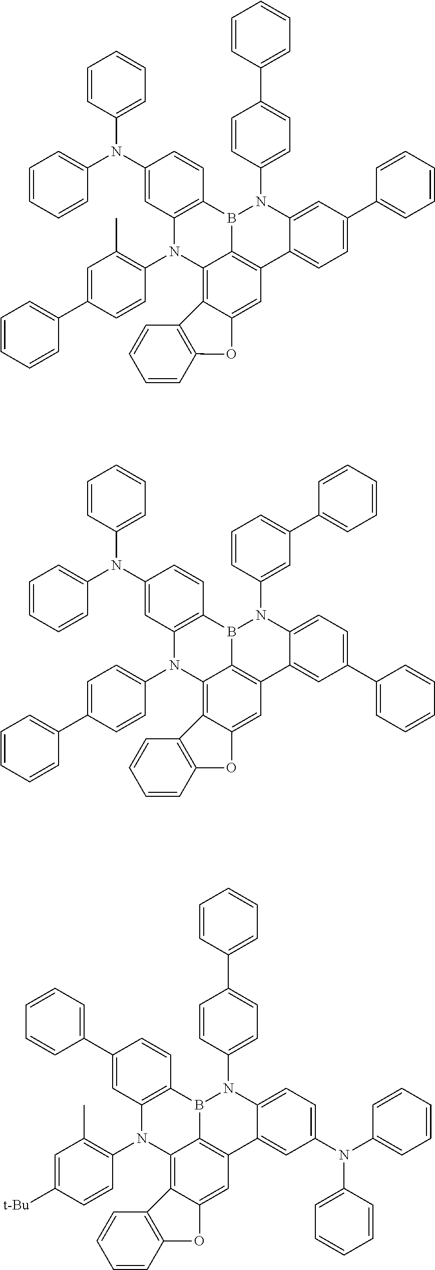 [SMILES: Cc1cc(-c2ccccc2)ccc1N1c2cc(N(c3ccccc3)c3ccccc3)ccc2B2c3c(cc4oc5ccccc5c4c31)-c1ccc(-c3ccccc3)cc1N2c1ccc(-c2ccccc2)cc1 ; c1ccc(-c2ccc(N3c4cc(N(c5ccccc5)c5ccccc5)ccc4B4c5c(cc6oc7ccccc7c6c53)-c3cc(-c5ccccc5)ccc3N4c3cccc(-c4ccccc4)c3)cc2)cc1 ; Cc1cc(C(C)(C)C)ccc1N1c2cc(-c3ccccc3)ccc2B2c3c(cc4oc5ccccc5c4c31)-c1cc(N(c3ccccc3)c3ccccc3)ccc1N2c1ccc(-c2ccccc2)cc1] 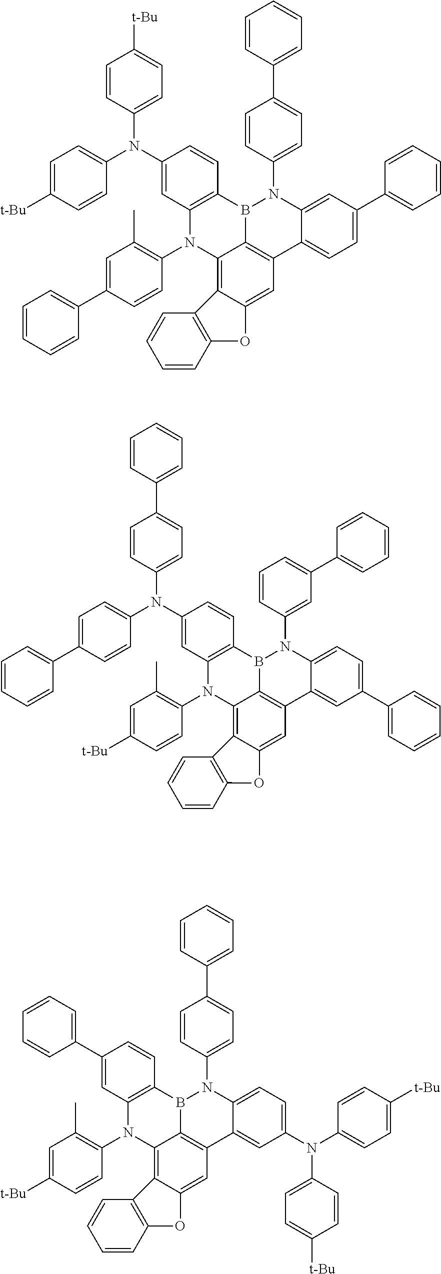 [SMILES: Cc1cc(-c2ccccc2)ccc1N1c2cc(N(c3ccc(C(C)(C)C)cc3)c3ccc(C(C)(C)C)cc3)ccc2B2c3c(cc4oc5ccccc5c4c31)-c1ccc(-c3ccccc3)cc1N2c1ccc(-c2ccccc2)cc1 ; Cc1cc(C(C)(C)C)ccc1N1c2cc(N(c3ccc(-c4ccccc4)cc3)c3ccc(-c4ccccc4)cc3)ccc2B2c3c(cc4oc5ccccc5c4c31)-c1cc(-c3ccccc3)ccc1N2c1cccc(-c2ccccc2)c1 ; Cc1cc(C(C)(C)C)ccc1N1c2cc(-c3ccccc3)ccc2B2c3c(cc4oc5ccccc5c4c31)-c1cc(N(c3ccc(C(C)(C)C)cc3)c3ccc(C(C)(C)C)cc3)ccc1N2c1ccc(-c2ccccc2)cc1] 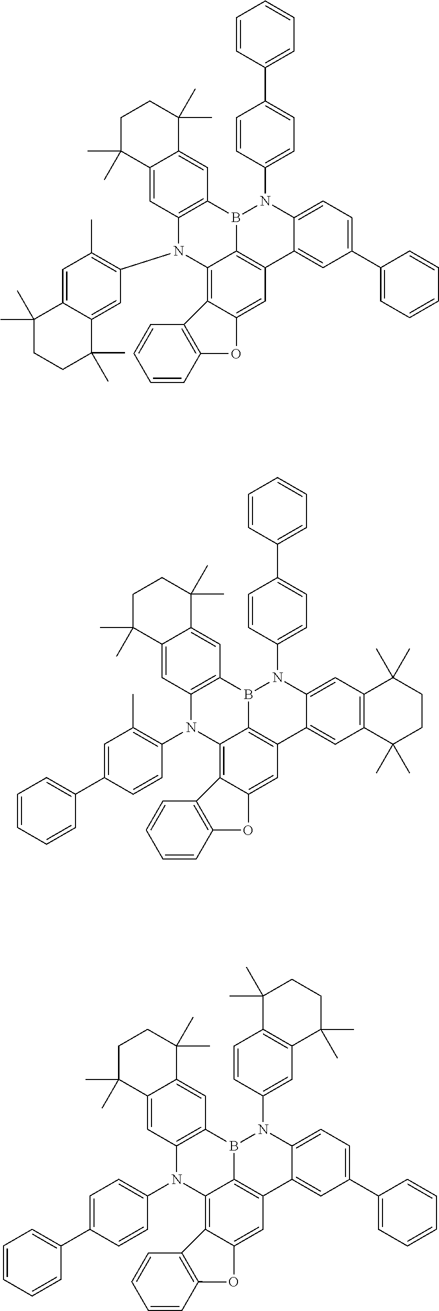 [SMILES: Cc1cc2c(cc1N1c3cc4c(cc3B3c5c(cc6oc7ccccc7c6c51)-c1cc(-c5ccccc5)ccc1N3c1ccc(-c3ccccc3)cc1)C(C)(C)CCC4(C)C)C(C)(C)CCC2(C)C ; Cc1cc(-c2ccccc2)ccc1N1c2cc3c(cc2B2c4c(cc5oc6ccccc6c5c41)-c1cc4c(cc1N2c1ccc(-c2ccccc2)cc1)C(C)(C)CCC4(C)C)C(C)(C)CCC3(C)C ; CC1(C)CCC(C)(C)c2cc(N3B4c5cc6c(cc5N(c5ccc(-c7ccccc7)cc5)c5c4c(cc4oc7ccccc7c54)-c4cc(-c5ccccc5)ccc43)C(C)(C)CCC6(C)C)ccc21] 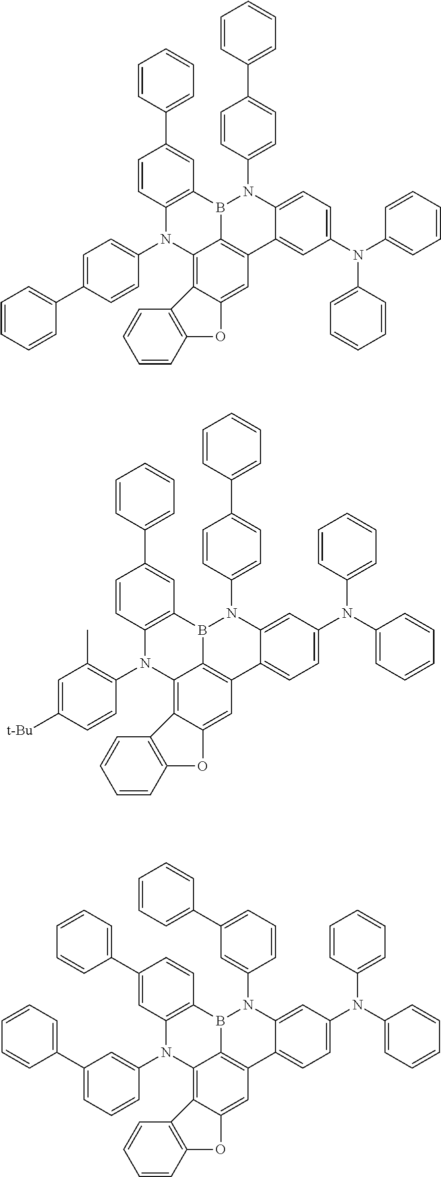 [SMILES: c1ccc(-c2ccc(N3B4c5cc(-c6ccccc6)ccc5N(c5ccc(-c6ccccc6)cc5)c5c4c(cc4oc6ccccc6c54)-c4cc(N(c5ccccc5)c5ccccc5)ccc43)cc2)cc1 ; Cc1cc(C(C)(C)C)ccc1N1c2ccc(-c3ccccc3)cc2B2c3c(cc4oc5ccccc5c4c31)-c1ccc(N(c3ccccc3)c3ccccc3)cc1N2c1ccc(-c2ccccc2)cc1 ; c1ccc(-c2cccc(N3B4c5ccc(-c6ccccc6)cc5N(c5cccc(-c6ccccc6)c5)c5c4c(cc4oc6ccccc6c54)-c4ccc(N(c5ccccc5)c5ccccc5)cc43)c2)cc1] 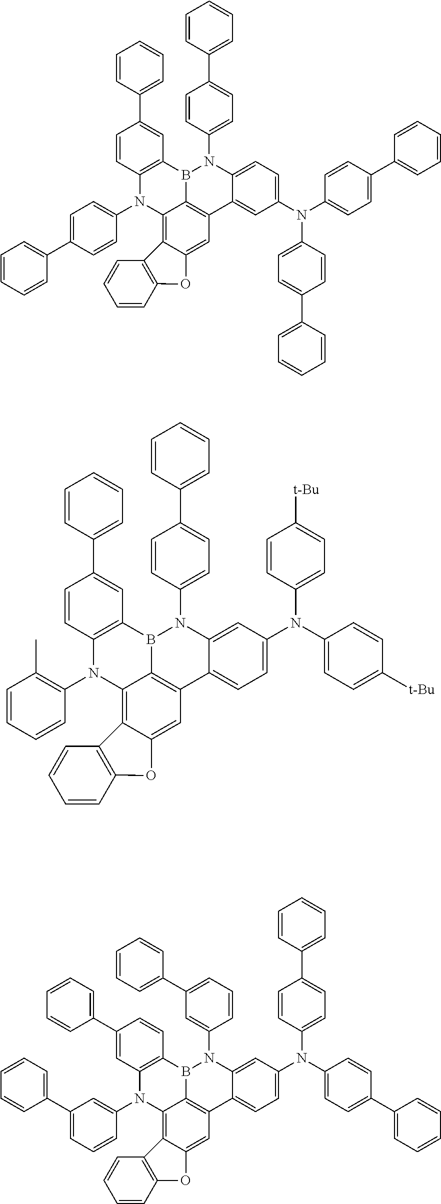 [SMILES: c1ccc(-c2ccc(N3B4c5cc(-c6ccccc6)ccc5N(c5ccc(-c6ccccc6)cc5)c5c4c(cc4oc6ccccc6c54)-c4cc(N(c5ccc(-c6ccccc6)cc5)c5ccc(-c6ccccc6)cc5)ccc43)cc2)cc1 ; Cc1ccccc1N1c2ccc(-c3ccccc3)cc2B2c3c(cc4oc5ccccc5c4c31)-c1ccc(N(c3ccc(C(C)(C)C)cc3)c3ccc(C(C)(C)C)cc3)cc1N2c1ccc(-c2ccccc2)cc1 ; c1ccc(-c2ccc(N(c3ccc(-c4ccccc4)cc3)c3ccc4c(c3)N(c3cccc(-c5ccccc5)c3)B3c5ccc(-c6ccccc6)cc5N(c5cccc(-c6ccccc6)c5)c5c3c-4cc3oc4ccccc4c53)cc2)cc1] 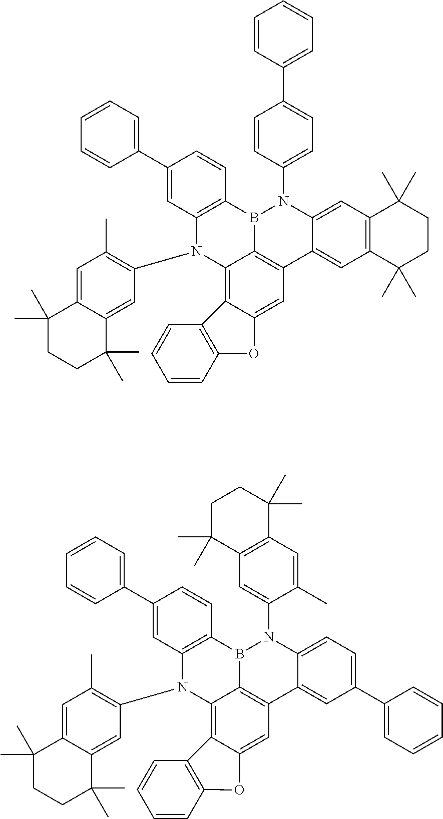 [SMILES: Cc1cc2c(cc1N1c3cc(-c4ccccc4)ccc3B3c4c(cc5oc6ccccc6c5c41)-c1cc4c(cc1N3c1ccc(-c3ccccc3)cc1)C(C)(C)CCC4(C)C)C(C)(C)CCC2(C)C ; Cc1cc2c(cc1N1B3c4ccc(-c5ccccc5)cc4N(c4cc5c(cc4C)C(C)(C)CCC5(C)C)c4c3c(cc3oc5ccccc5c43)-c3cc(-c4ccccc4)ccc31)C(C)(C)CCC2(C)C] 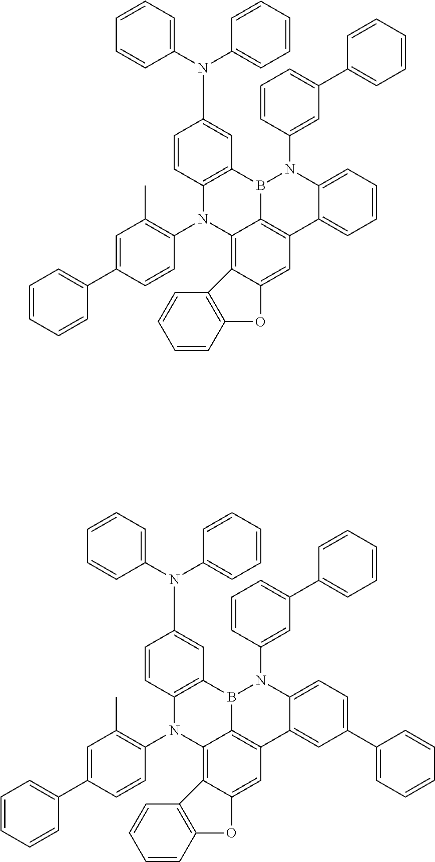 [SMILES: Cc1cc(-c2ccccc2)ccc1N1c2ccc(N(c3ccccc3)c3ccccc3)cc2B2c3c(cc4oc5ccccc5c4c31)-c1ccccc1N2c1cccc(-c2ccccc2)c1 ; Cc1cc(-c2ccccc2)ccc1N1c2ccc(N(c3ccccc3)c3ccccc3)cc2B2c3c(cc4oc5ccccc5c4c31)-c1cc(-c3ccccc3)ccc1N2c1cccc(-c2ccccc2)c1] 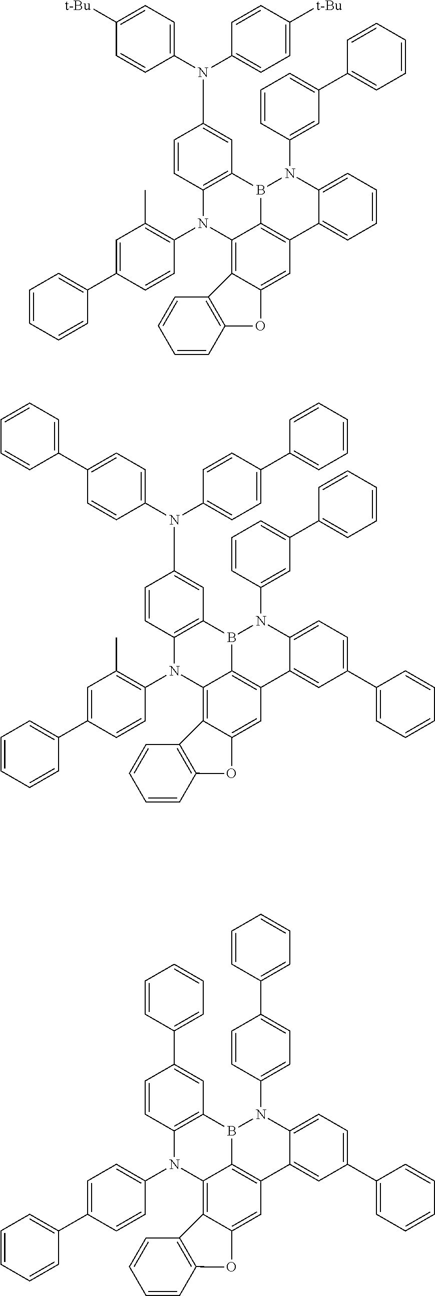 [SMILES: Cc1cc(-c2ccccc2)ccc1N1c2ccc(N(c3ccc(C(C)(C)C)cc3)c3ccc(C(C)(C)C)cc3)cc2B2c3c(cc4oc5ccccc5c4c31)-c1ccccc1N2c1cccc(-c2ccccc2)c1 ; Cc1cc(-c2ccccc2)ccc1N1c2ccc(N(c3ccc(-c4ccccc4)cc3)c3ccc(-c4ccccc4)cc3)cc2B2c3c(cc4oc5ccccc5c4c31)-c1cc(-c3ccccc3)ccc1N2c1cccc(-c2ccccc2)c1 ; c1ccc(-c2ccc(N3B4c5cc(-c6ccccc6)ccc5N(c5ccc(-c6ccccc6)cc5)c5c4c(cc4oc6ccccc6c54)-c4cc(-c5ccccc5)ccc43)cc2)cc1] 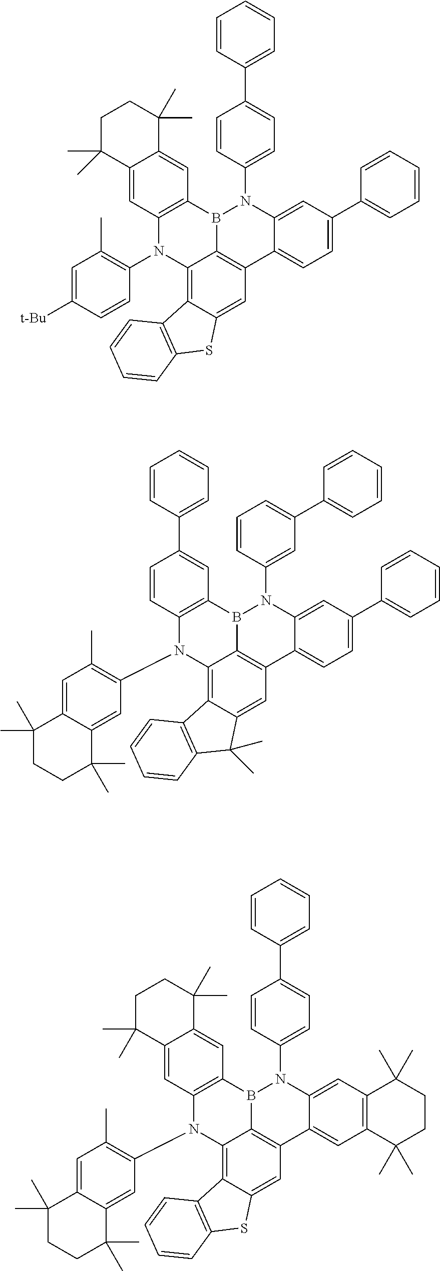 [SMILES: Cc1cc(C(C)(C)C)ccc1N1c2cc3c(cc2B2c4c(cc5sc6ccccc6c5c41)-c1ccc(-c4ccccc4)cc1N2c1ccc(-c2ccccc2)cc1)C(C)(C)CCC3(C)C ; Cc1cc2c(cc1N1c3ccc(-c4ccccc4)cc3B3c4c(cc5c(c41)-c1ccccc1C5(C)C)-c1ccc(-c4ccccc4)cc1N3c1cccc(-c3ccccc3)c1)C(C)(C)CCC2(C)C ; Cc1cc2c(cc1N1c3cc4c(cc3B3c5c(cc6sc7ccccc7c6c51)-c1cc5c(cc1N3c1ccc(-c3ccccc3)cc1)C(C)(C)CCC5(C)C)C(C)(C)CCC4(C)C)C(C)(C)CCC2(C)C] 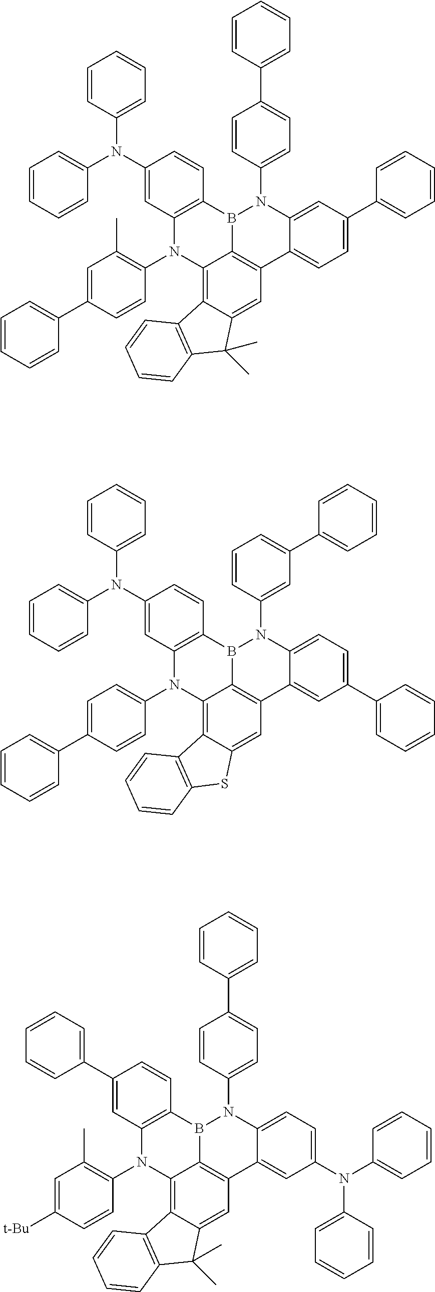 [SMILES: Cc1cc(-c2ccccc2)ccc1N1c2cc(N(c3ccccc3)c3ccccc3)ccc2B2c3c(cc4c(c31)-c1ccccc1C4(C)C)-c1ccc(-c3ccccc3)cc1N2c1ccc(-c2ccccc2)cc1 ; c1ccc(-c2ccc(N3c4cc(N(c5ccccc5)c5ccccc5)ccc4B4c5c(cc6sc7ccccc7c6c53)-c3cc(-c5ccccc5)ccc3N4c3cccc(-c4ccccc4)c3)cc2)cc1 ; Cc1cc(C(C)(C)C)ccc1N1c2cc(-c3ccccc3)ccc2B2c3c(cc4c(c31)-c1ccccc1C4(C)C)-c1cc(N(c3ccccc3)c3ccccc3)ccc1N2c1ccc(-c2ccccc2)cc1] 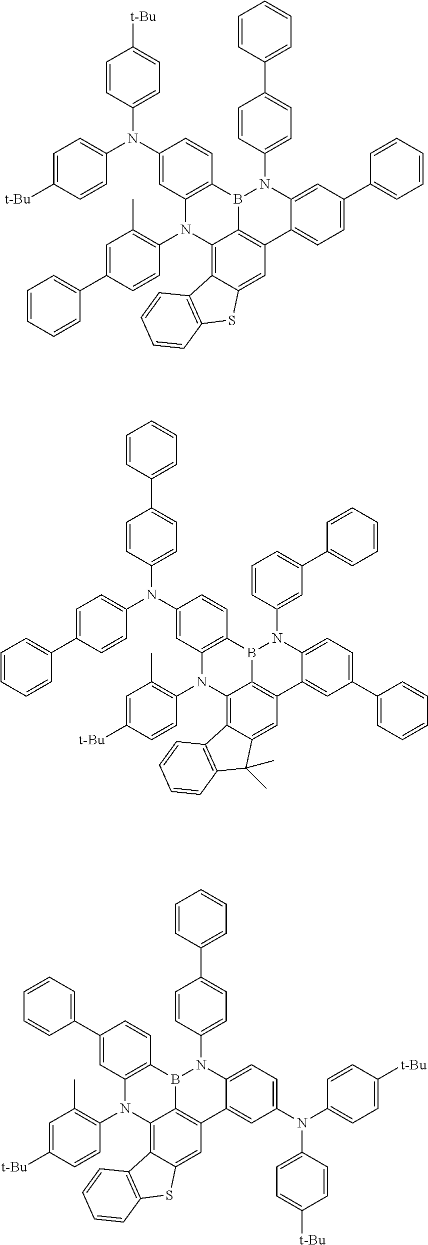 [SMILES: Cc1cc(-c2ccccc2)ccc1N1c2cc(N(c3ccc(C(C)(C)C)cc3)c3ccc(C(C)(C)C)cc3)ccc2B2c3c(cc4sc5ccccc5c4c31)-c1ccc(-c3ccccc3)cc1N2c1ccc(-c2ccccc2)cc1 ; Cc1cc(C(C)(C)C)ccc1N1c2cc(N(c3ccc(-c4ccccc4)cc3)c3ccc(-c4ccccc4)cc3)ccc2B2c3c(cc4c(c31)-c1ccccc1C4(C)C)-c1cc(-c3ccccc3)ccc1N2c1cccc(-c2ccccc2)c1 ; Cc1cc(C(C)(C)C)ccc1N1c2cc(-c3ccccc3)ccc2B2c3c(cc4sc5ccccc5c4c31)-c1cc(N(c3ccc(C(C)(C)C)cc3)c3ccc(C(C)(C)C)cc3)ccc1N2c1ccc(-c2ccccc2)cc1] 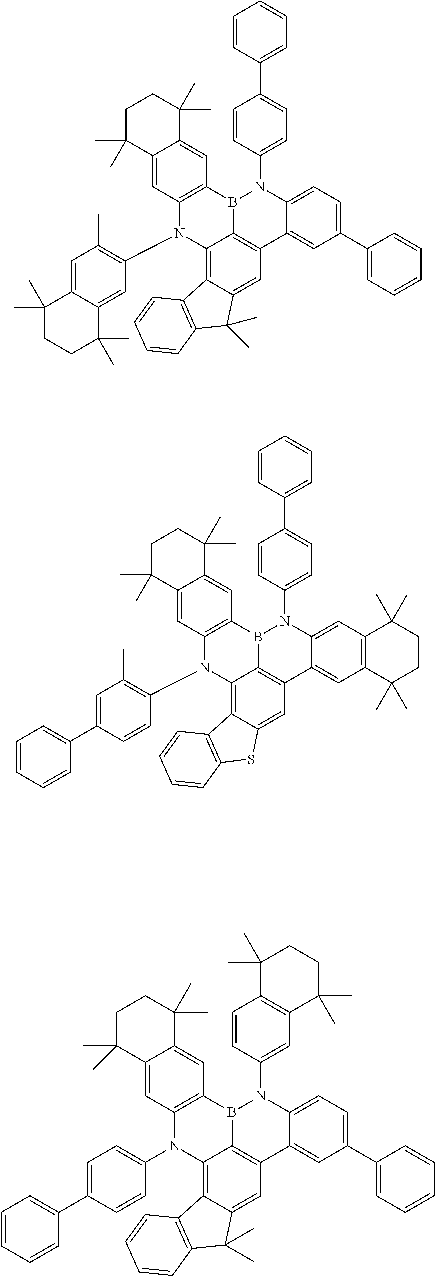 [SMILES: Cc1cc2c(cc1N1c3cc4c(cc3B3c5c(cc6c(c51)-c1ccccc1C6(C)C)-c1cc(-c5ccccc5)ccc1N3c1ccc(-c3ccccc3)cc1)C(C)(C)CCC4(C)C)C(C)(C)CCC2(C)C ; Cc1cc(-c2ccccc2)ccc1N1c2cc3c(cc2B2c4c(cc5sc6ccccc6c5c41)-c1cc4c(cc1N2c1ccc(-c2ccccc2)cc1)C(C)(C)CCC4(C)C)C(C)(C)CCC3(C)C ; CC1(C)CCC(C)(C)c2cc(N3B4c5cc6c(cc5N(c5ccc(-c7ccccc7)cc5)c5c4c(cc4c5-c5ccccc5C4(C)C)-c4cc(-c5ccccc5)ccc43)C(C)(C)CCC6(C)C)ccc21] 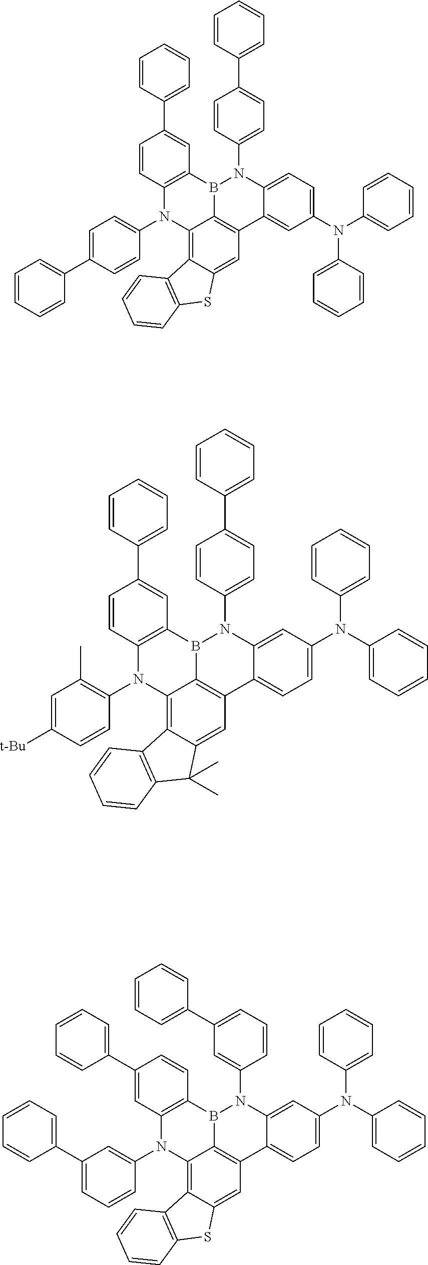 [SMILES: c1ccc(-c2ccc(N3B4c5cc(-c6ccccc6)ccc5N(c5ccc(-c6ccccc6)cc5)c5c4c(cc4sc6ccccc6c54)-c4cc(N(c5ccccc5)c5ccccc5)ccc43)cc2)cc1 ; Cc1cc(C(C)(C)C)ccc1N1c2ccc(-c3ccccc3)cc2B2c3c(cc4c(c31)-c1ccccc1C4(C)C)-c1ccc(N(c3ccccc3)c3ccccc3)cc1N2c1ccc(-c2ccccc2)cc1 ; c1ccc(-c2cccc(N3B4c5ccc(-c6ccccc6)cc5N(c5cccc(-c6ccccc6)c5)c5c4c(cc4sc6ccccc6c54)-c4ccc(N(c5ccccc5)c5ccccc5)cc43)c2)cc1] 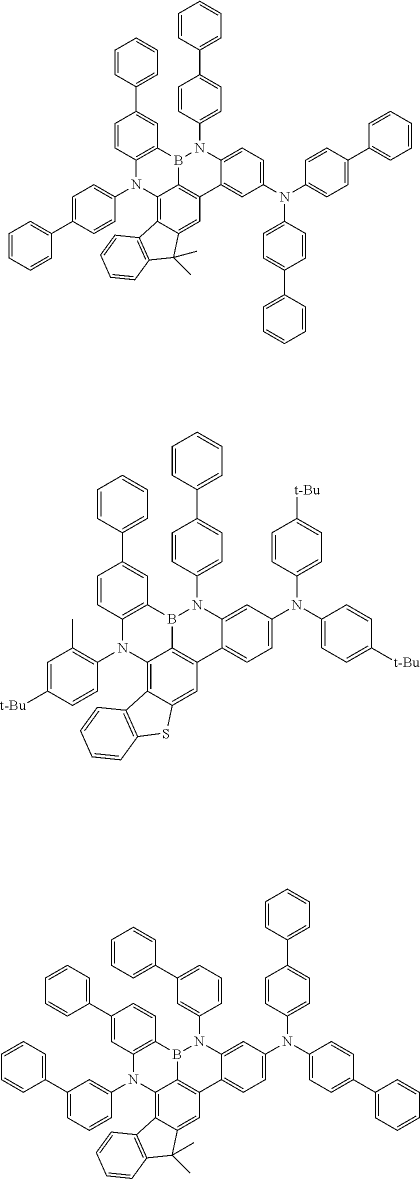 [SMILES: CC1(C)c2ccccc2-c2c1cc1c3c2N(c2ccc(-c4ccccc4)cc2)c2ccc(-c4ccccc4)cc2B3N(c2ccc(-c3ccccc3)cc2)c2ccc(N(c3ccc(-c4ccccc4)cc3)c3ccc(-c4ccccc4)cc3)cc2-1 ; Cc1cc(C(C)(C)C)ccc1N1c2ccc(-c3ccccc3)cc2B2c3c(cc4sc5ccccc5c4c31)-c1ccc(N(c3ccc(C(C)(C)C)cc3)c3ccc(C(C)(C)C)cc3)cc1N2c1ccc(-c2ccccc2)cc1 ; CC1(C)c2ccccc2-c2c1cc1c3c2N(c2cccc(-c4ccccc4)c2)c2cc(-c4ccccc4)ccc2B3N(c2cccc(-c3ccccc3)c2)c2cc(N(c3ccc(-c4ccccc4)cc3)c3ccc(-c4ccccc4)cc3)ccc2-1] 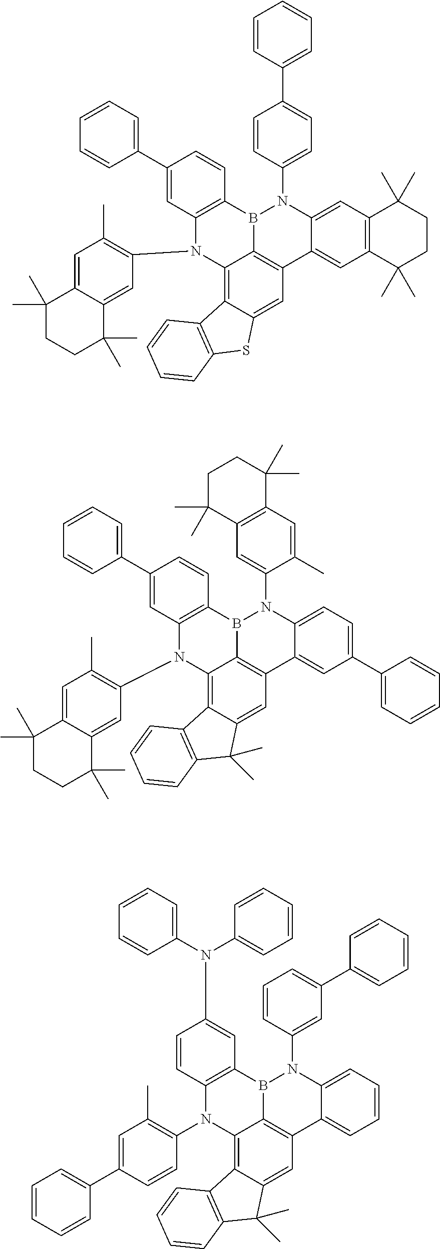 [SMILES: Cc1cc2c(cc1N1c3cc(-c4ccccc4)ccc3B3c4c(cc5sc6ccccc6c5c41)-c1cc4c(cc1N3c1ccc(-c3ccccc3)cc1)C(C)(C)CCC4(C)C)C(C)(C)CCC2(C)C ; Cc1cc2c(cc1N1B3c4ccc(-c5ccccc5)cc4N(c4cc5c(cc4C)C(C)(C)CCC5(C)C)c4c3c(cc3c4-c4ccccc4C3(C)C)-c3cc(-c4ccccc4)ccc31)C(C)(C)CCC2(C)C ; Cc1cc(-c2ccccc2)ccc1N1c2ccc(N(c3ccccc3)c3ccccc3)cc2B2c3c(cc4c(c31)-c1ccccc1C4(C)C)-c1ccccc1N2c1cccc(-c2ccccc2)c1] 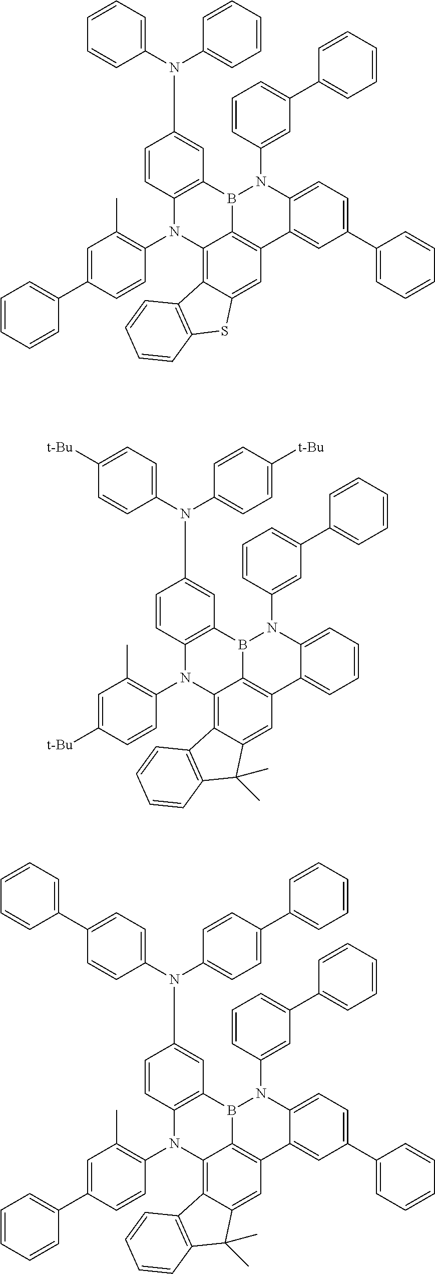 [SMILES: Cc1cc(-c2ccccc2)ccc1N1c2ccc(N(c3ccccc3)c3ccccc3)cc2B2c3c(cc4sc5ccccc5c4c31)-c1cc(-c3ccccc3)ccc1N2c1cccc(-c2ccccc2)c1 ; Cc1cc(C(C)(C)C)ccc1N1c2ccc(N(c3ccc(C(C)(C)C)cc3)c3ccc(C(C)(C)C)cc3)cc2B2c3c(cc4c(c31)-c1ccccc1C4(C)C)-c1ccccc1N2c1cccc(-c2ccccc2)c1 ; Cc1cc(-c2ccccc2)ccc1N1c2ccc(N(c3ccc(-c4ccccc4)cc3)c3ccc(-c4ccccc4)cc3)cc2B2c3c(cc4c(c31)-c1ccccc1C4(C)C)-c1cc(-c3ccccc3)ccc1N2c1cccc(-c2ccccc2)c1] 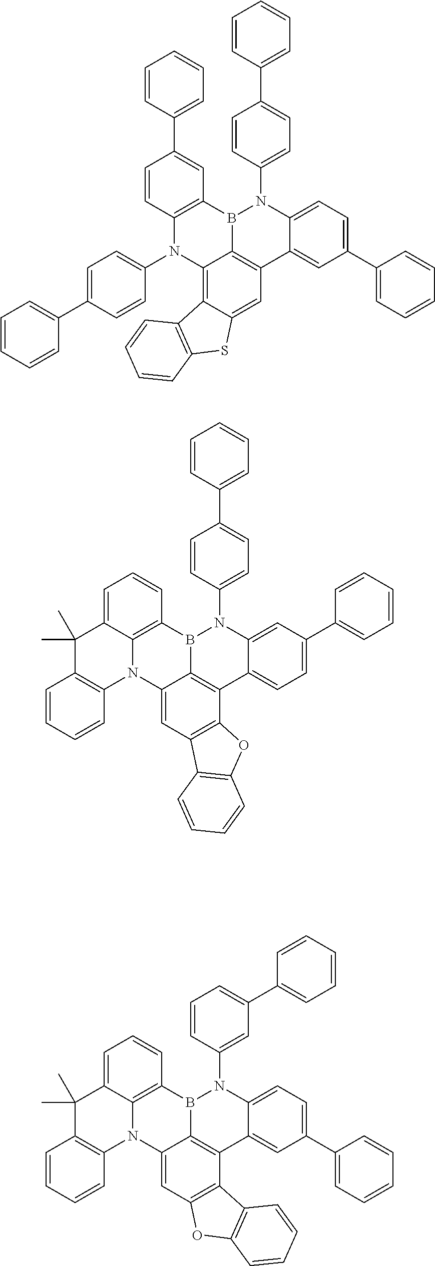 [SMILES: c1ccc(-c2ccc(N3B4c5cc(-c6ccccc6)ccc5N(c5ccc(-c6ccccc6)cc5)c5c4c(cc4sc6ccccc6c54)-c4cc(-c5ccccc5)ccc43)cc2)cc1 ; CC1(C)c2ccccc2N2c3cc4c(oc5ccccc54)c4c3B(c3cccc1c32)N(c1ccc(-c2ccccc2)cc1)c1cc(-c2ccccc2)ccc1-4 ; CC1(C)c2ccccc2N2c3cc4oc5ccccc5c4c4c3B(c3cccc1c32)N(c1cccc(-c2ccccc2)c1)c1ccc(-c2ccccc2)cc1-4] 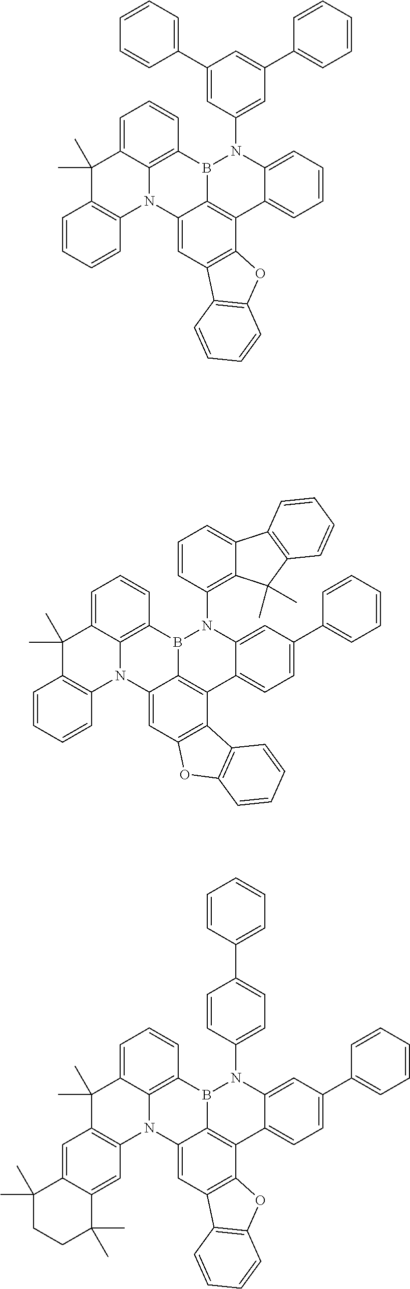 [SMILES: CC1(C)c2ccccc2N2c3cc4c(oc5ccccc54)c4c3B(c3cccc1c32)N(c1cc(-c2ccccc2)cc(-c2ccccc2)c1)c1ccccc1-4 ; CC1(C)c2ccccc2N2c3cc4oc5ccccc5c4c4c3B(c3cccc1c32)N(c1cccc2c1C(C)(C)c1ccccc1-2)c1cc(-c2ccccc2)ccc1-4 ; CC1(C)CCC(C)(C)c2cc3c(cc21)N1c2cc4c(oc5ccccc54)c4c2B(c2cccc(c21)C3(C)C)N(c1ccc(-c2ccccc2)cc1)c1cc(-c2ccccc2)ccc1-4] 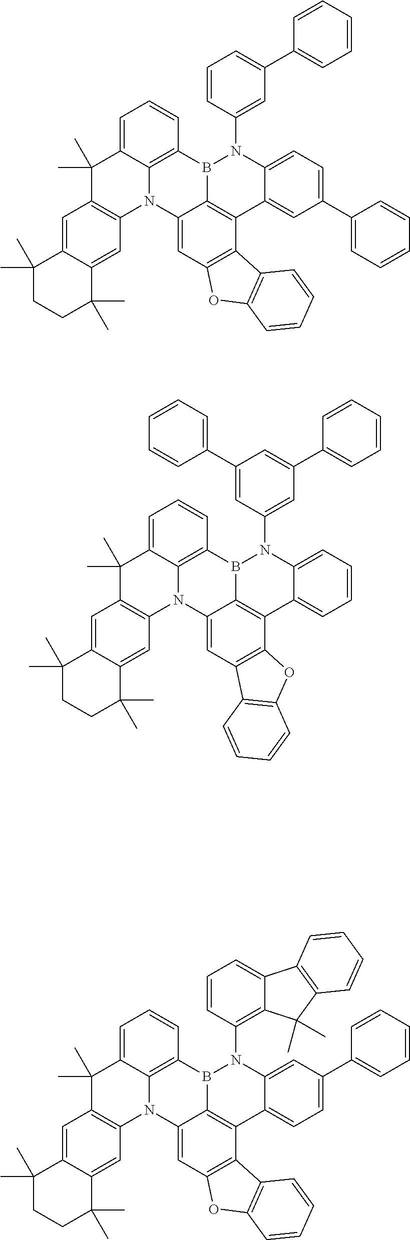 [SMILES: CC1(C)CCC(C)(C)c2cc3c(cc21)N1c2cc4oc5ccccc5c4c4c2B(c2cccc(c21)C3(C)C)N(c1cccc(-c2ccccc2)c1)c1ccc(-c2ccccc2)cc1-4 ; CC1(C)CCC(C)(C)c2cc3c(cc21)N1c2cc4c(oc5ccccc54)c4c2B(c2cccc(c21)C3(C)C)N(c1cc(-c2ccccc2)cc(-c2ccccc2)c1)c1ccccc1-4 ; CC1(C)CCC(C)(C)c2cc3c(cc21)N1c2cc4oc5ccccc5c4c4c2B(c2cccc(c21)C3(C)C)N(c1cccc2c1C(C)(C)c1ccccc1-2)c1cc(-c2ccccc2)ccc1-4] 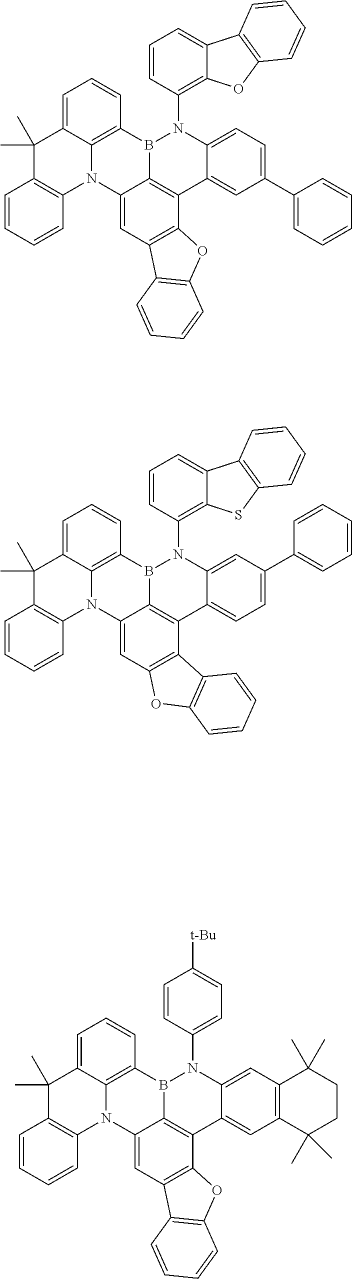 [SMILES: CC1(C)c2ccccc2N2c3cc4c(oc5ccccc54)c4c3B(c3cccc1c32)N(c1cccc2c1oc1ccccc12)c1ccc(-c2ccccc2)cc1-4 ; CC1(C)c2ccccc2N2c3cc4oc5ccccc5c4c4c3B(c3cccc1c32)N(c1cccc2c1sc1ccccc12)c1cc(-c2ccccc2)ccc1-4 ; CC(C)(C)c1ccc(N2B3c4cccc5c4N(c4ccccc4C5(C)C)c4cc5c(oc6ccccc65)c(c43)-c3cc4c(cc32)C(C)(C)CCC4(C)C)cc1] 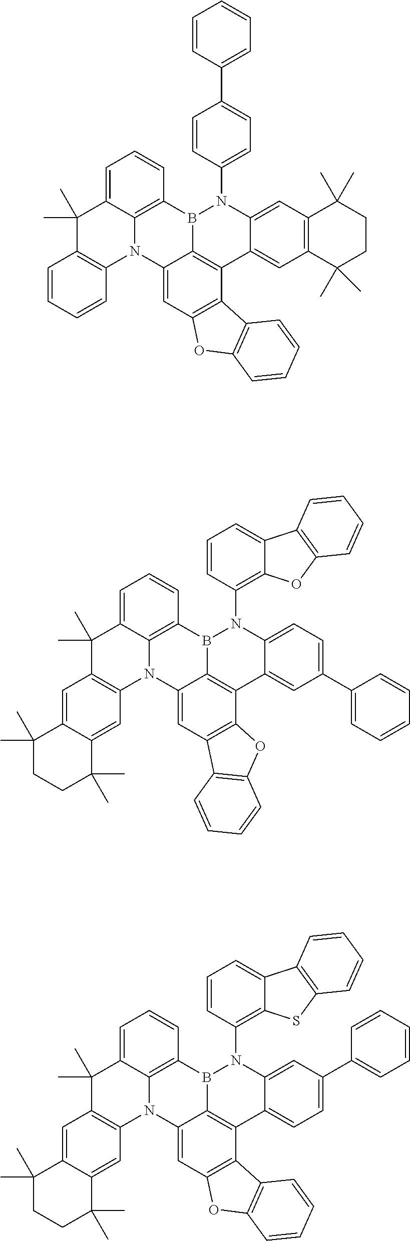 [SMILES: CC1(C)CCC(C)(C)c2cc3c(cc21)-c1c2c(cc4oc5ccccc5c14)N1c4ccccc4C(C)(C)c4cccc(c41)B2N3c1ccc(-c2ccccc2)cc1 ; CC1(C)CCC(C)(C)c2cc3c(cc21)N1c2cc4c(oc5ccccc54)c4c2B(c2cccc(c21)C3(C)C)N(c1cccc2c1oc1ccccc12)c1ccc(-c2ccccc2)cc1-4 ; CC1(C)CCC(C)(C)c2cc3c(cc21)N1c2cc4oc5ccccc5c4c4c2B(c2cccc(c21)C3(C)C)N(c1cccc2c1sc1ccccc12)c1cc(-c2ccccc2)ccc1-4] 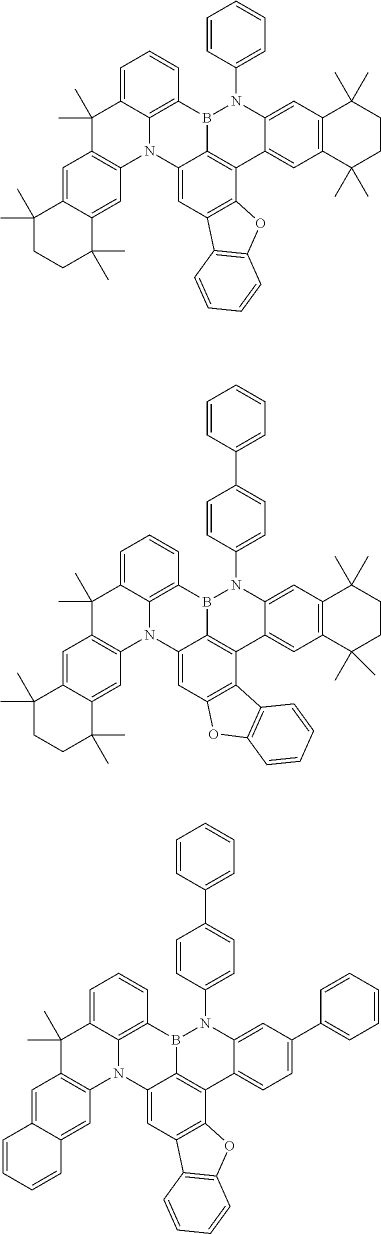 [SMILES: CC1(C)CCC(C)(C)c2cc3c(cc21)-c1c2c(cc4c1oc1ccccc14)N1c4cc5c(cc4C(C)(C)c4cccc(c41)B2N3c1ccccc1)C(C)(C)CCC5(C)C ; CC1(C)CCC(C)(C)c2cc3c(cc21)-c1c2c(cc4oc5ccccc5c14)N1c4cc5c(cc4C(C)(C)c4cccc(c41)B2N3c1ccc(-c2ccccc2)cc1)C(C)(C)CCC5(C)C ; CC1(C)c2cc3ccccc3cc2N2c3cc4c(oc5ccccc54)c4c3B(c3cccc1c32)N(c1ccc(-c2ccccc2)cc1)c1cc(-c2ccccc2)ccc1-4] 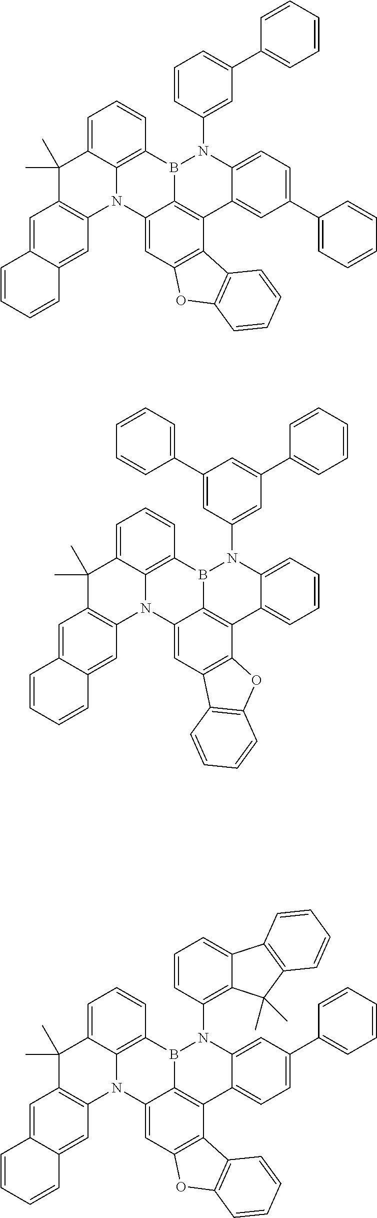 [SMILES: CC1(C)c2cc3ccccc3cc2N2c3cc4oc5ccccc5c4c4c3B(c3cccc1c32)N(c1cccc(-c2ccccc2)c1)c1ccc(-c2ccccc2)cc1-4 ; CC1(C)c2cc3ccccc3cc2N2c3cc4c(oc5ccccc54)c4c3B(c3cccc1c32)N(c1cc(-c2ccccc2)cc(-c2ccccc2)c1)c1ccccc1-4 ; CC1(C)c2cc3ccccc3cc2N2c3cc4oc5ccccc5c4c4c3B(c3cccc1c32)N(c1cccc2c1C(C)(C)c1ccccc1-2)c1cc(-c2ccccc2)ccc1-4] 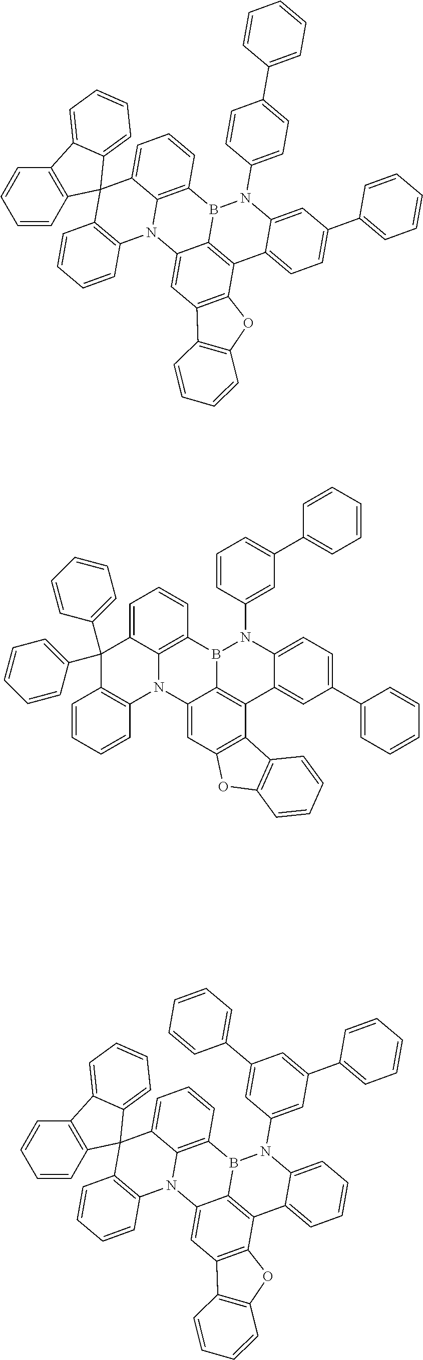 [SMILES: c1ccc(-c2ccc(N3B4c5cccc6c5N(c5ccccc5C65c6ccccc6-c6ccccc65)c5cc6c(oc7ccccc76)c(c54)-c4ccc(-c5ccccc5)cc43)cc2)cc1 ; c1ccc(-c2cccc(N3B4c5cccc6c5N(c5ccccc5C6(c5ccccc5)c5ccccc5)c5cc6oc7ccccc7c6c(c54)-c4cc(-c5ccccc5)ccc43)c2)cc1 ; c1ccc(-c2cc(-c3ccccc3)cc(N3B4c5cccc6c5N(c5ccccc5C65c6ccccc6-c6ccccc65)c5cc6c(oc7ccccc76)c(c54)-c4ccccc43)c2)cc1] 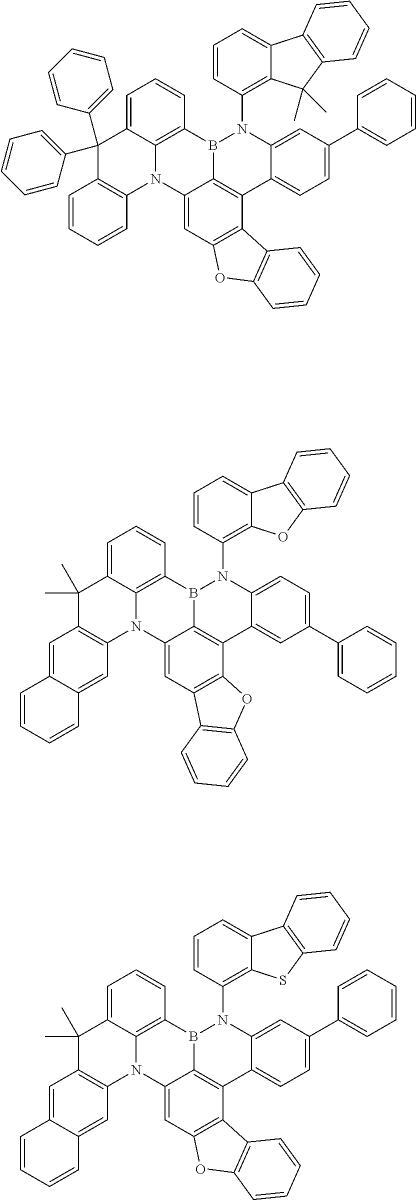 [SMILES: CC1(C)c2ccccc2-c2cccc(N3B4c5cccc6c5N(c5ccccc5C6(c5ccccc5)c5ccccc5)c5cc6oc7ccccc7c6c(c54)-c4ccc(-c5ccccc5)cc43)c21 ; CC1(C)c2cc3ccccc3cc2N2c3cc4c(oc5ccccc54)c4c3B(c3cccc1c32)N(c1cccc2c1oc1ccccc12)c1ccc(-c2ccccc2)cc1-4 ; CC1(C)c2cc3ccccc3cc2N2c3cc4oc5ccccc5c4c4c3B(c3cccc1c32)N(c1cccc2c1sc1ccccc12)c1cc(-c2ccccc2)ccc1-4] 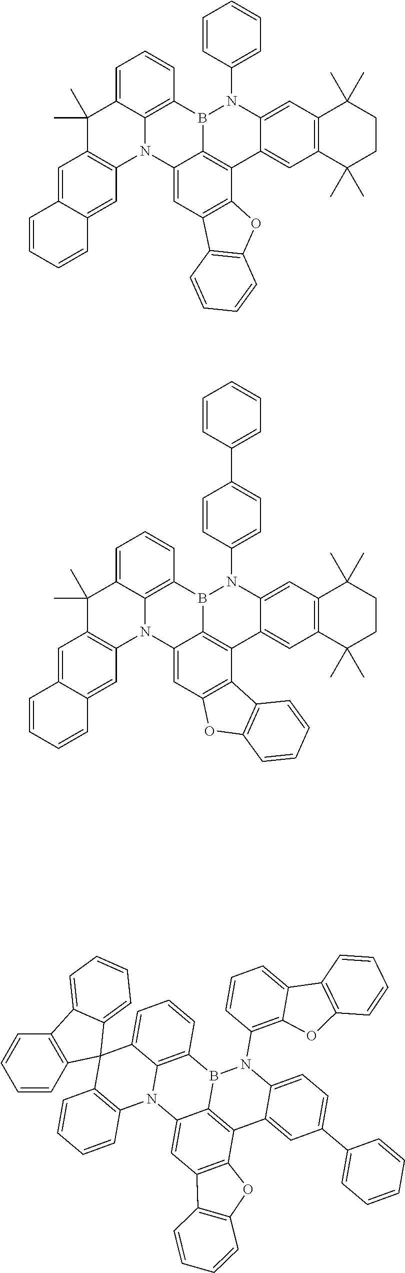 [SMILES: CC1(C)CCC(C)(C)c2cc3c(cc21)-c1c2c(cc4c1oc1ccccc14)N1c4cc5ccccc5cc4C(C)(C)c4cccc(c41)B2N3c1ccccc1 ; CC1(C)CCC(C)(C)c2cc3c(cc21)-c1c2c(cc4oc5ccccc5c14)N1c4cc5ccccc5cc4C(C)(C)c4cccc(c41)B2N3c1ccc(-c2ccccc2)cc1 ; c1ccc(-c2ccc3c(c2)-c2c4c(cc5c2oc2ccccc25)N2c5ccccc5C5(c6ccccc6-c6ccccc65)c5cccc(c52)B4N3c2cccc3c2oc2ccccc23)cc1] 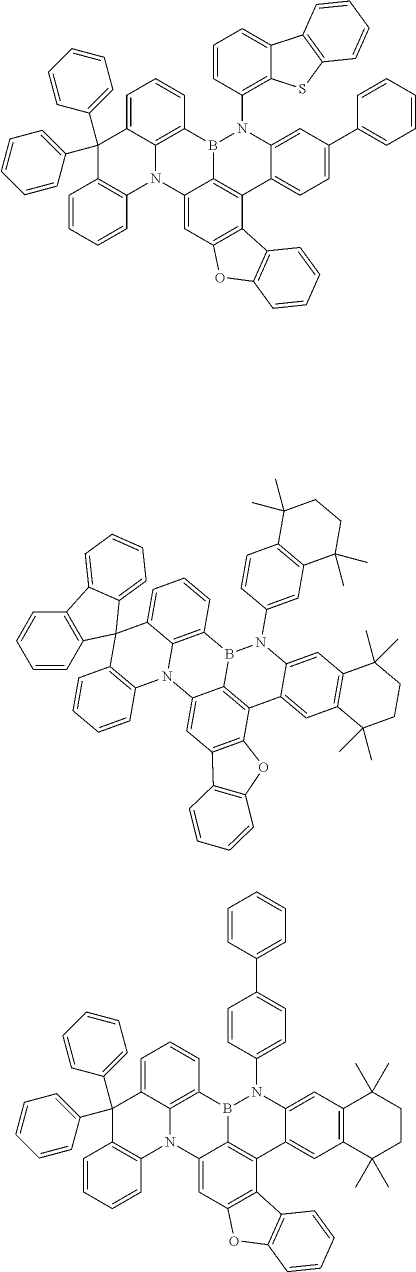 [SMILES: c1ccc(-c2ccc3c(c2)N(c2cccc4c2sc2ccccc24)B2c4cccc5c4N(c4ccccc4C5(c4ccccc4)c4ccccc4)c4cc5oc6ccccc6c5c-3c42)cc1 ; CC1(C)CCC(C)(C)c2cc(N3B4c5cccc6c5N(c5ccccc5C65c6ccccc6-c6ccccc65)c5cc6c(oc7ccccc76)c(c54)-c4cc5c(cc43)C(C)(C)CCC5(C)C)ccc21 ; CC1(C)CCC(C)(C)c2cc3c(cc21)-c1c2c(cc4oc5ccccc5c14)N1c4ccccc4C(c4ccccc4)(c4ccccc4)c4cccc(c41)B2N3c1ccc(-c2ccccc2)cc1] 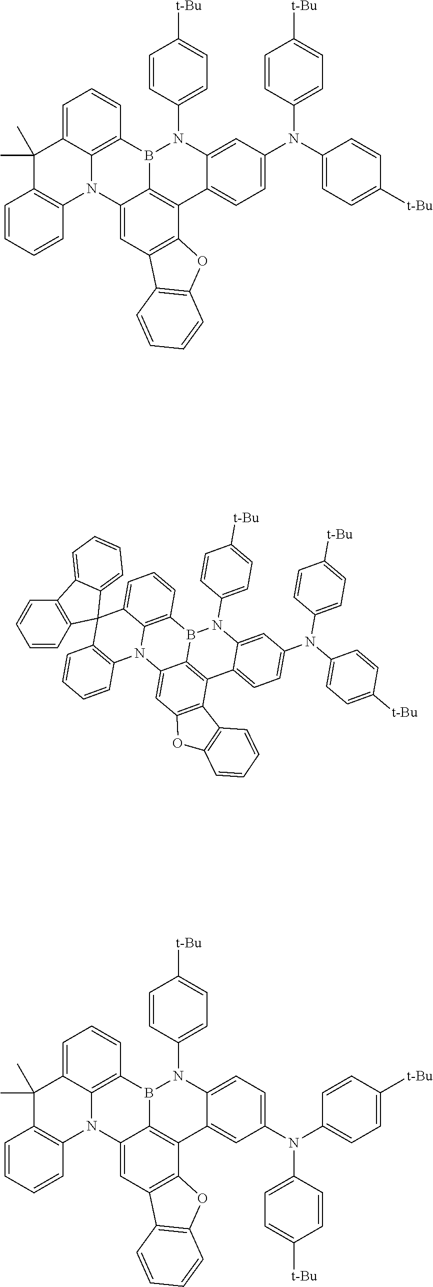 [SMILES: CC(C)(C)c1ccc(N2B3c4cccc5c4N(c4ccccc4C5(C)C)c4cc5c(oc6ccccc65)c(c43)-c3ccc(N(c4ccc(C(C)(C)C)cc4)c4ccc(C(C)(C)C)cc4)cc32)cc1 ; CC(C)(C)c1ccc(N2B3c4cccc5c4N(c4ccccc4C54c5ccccc5-c5ccccc54)c4cc5oc6ccccc6c5c(c43)-c3ccc(N(c4ccc(C(C)(C)C)cc4)c4ccc(C(C)(C)C)cc4)cc32)cc1 ; CC(C)(C)c1ccc(N2B3c4cccc5c4N(c4ccccc4C5(C)C)c4cc5c(oc6ccccc65)c(c43)-c3cc(N(c4ccc(C(C)(C)C)cc4)c4ccc(C(C)(C)C)cc4)ccc32)cc1] 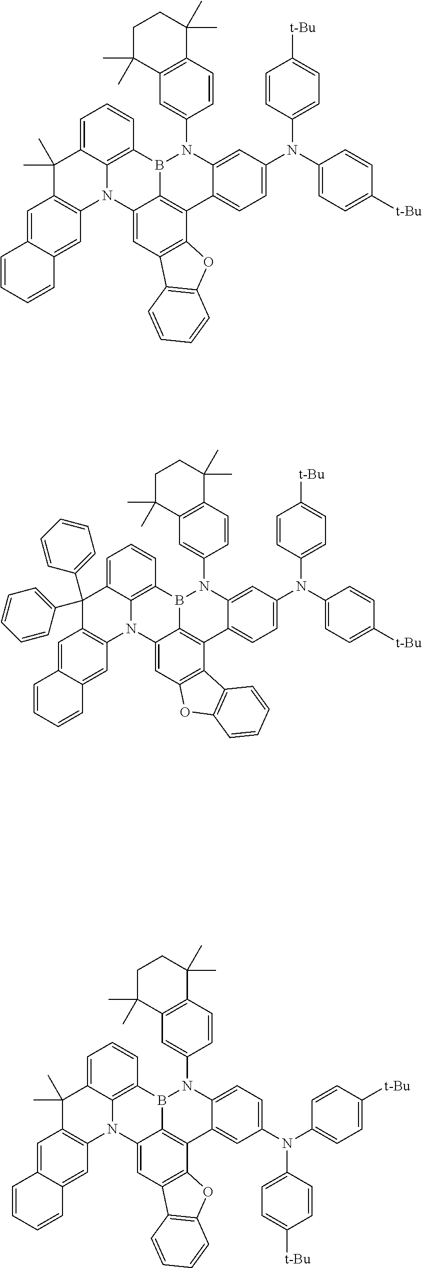 [SMILES: CC(C)(C)c1ccc(N(c2ccc(C(C)(C)C)cc2)c2ccc3c(c2)N(c2ccc4c(c2)C(C)(C)CCC4(C)C)B2c4cccc5c4N(c4cc6ccccc6cc4C5(C)C)c4cc5c(oc6ccccc65)c-3c42)cc1 ; CC(C)(C)c1ccc(N(c2ccc(C(C)(C)C)cc2)c2ccc3c(c2)N(c2ccc4c(c2)C(C)(C)CCC4(C)C)B2c4cccc5c4N(c4cc6ccccc6cc4C5(c4ccccc4)c4ccccc4)c4cc5oc6ccccc6c5c-3c42)cc1 ; CC(C)(C)c1ccc(N(c2ccc(C(C)(C)C)cc2)c2ccc3c(c2)-c2c4c(cc5c2oc2ccccc25)N2c5cc6ccccc6cc5C(C)(C)c5cccc(c52)B4N3c2ccc3c(c2)C(C)(C)CCC3(C)C)cc1] 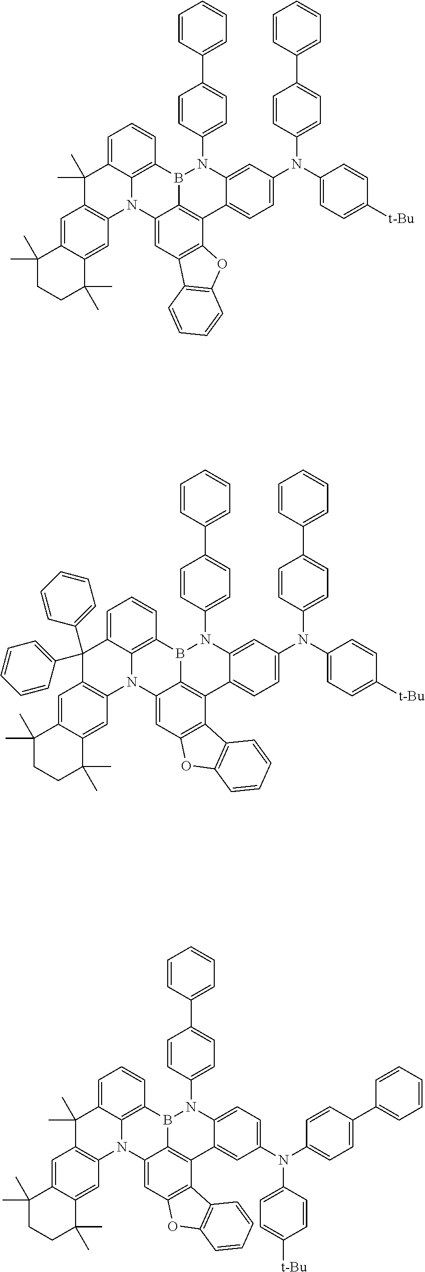 [SMILES: CC(C)(C)c1ccc(N(c2ccc(-c3ccccc3)cc2)c2ccc3c(c2)N(c2ccc(-c4ccccc4)cc2)B2c4cccc5c4N(c4cc6c(cc4C5(C)C)C(C)(C)CCC6(C)C)c4cc5c(oc6ccccc65)c-3c42)cc1 ; CC(C)(C)c1ccc(N(c2ccc(-c3ccccc3)cc2)c2ccc3c(c2)N(c2ccc(-c4ccccc4)cc2)B2c4cccc5c4N(c4cc6c(cc4C5(c4ccccc4)c4ccccc4)C(C)(C)CCC6(C)C)c4cc5oc6ccccc6c5c-3c42)cc1 ; CC(C)(C)c1ccc(N(c2ccc(-c3ccccc3)cc2)c2ccc3c(c2)-c2c4c(cc5oc6ccccc6c25)N2c5cc6c(cc5C(C)(C)c5cccc(c52)B4N3c2ccc(-c3ccccc3)cc2)C(C)(C)CCC6(C)C)cc1] 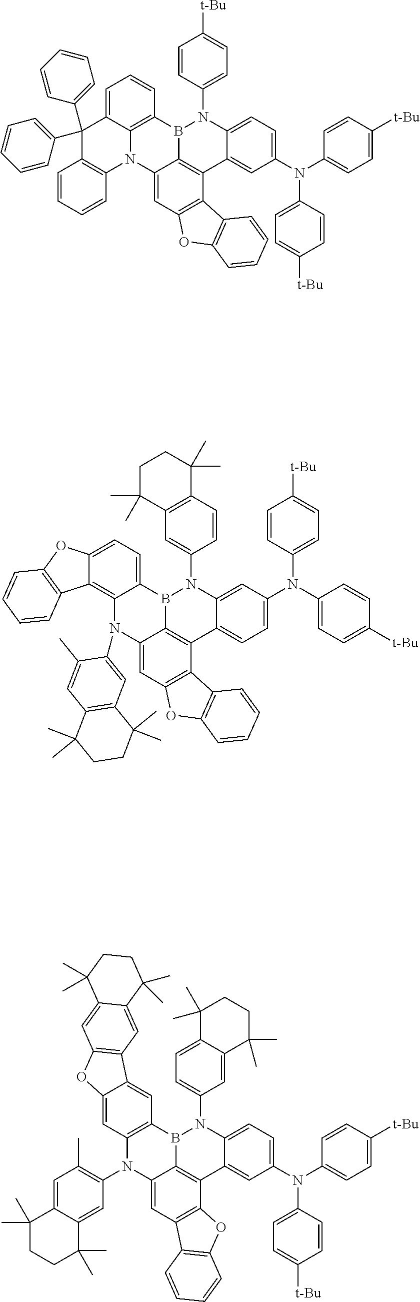 [SMILES: CC(C)(C)c1ccc(N2B3c4cccc5c4N(c4ccccc4C5(c4ccccc4)c4ccccc4)c4cc5oc6ccccc6c5c(c43)-c3cc(N(c4ccc(C(C)(C)C)cc4)c4ccc(C(C)(C)C)cc4)ccc32)cc1 ; Cc1cc2c(cc1N1c3cc4oc5ccccc5c4c4c3B(c3ccc5oc6ccccc6c5c31)N(c1ccc3c(c1)C(C)(C)CCC3(C)C)c1cc(N(c3ccc(C(C)(C)C)cc3)c3ccc(C(C)(C)C)cc3)ccc1-4)C(C)(C)CCC2(C)C ; Cc1cc2c(cc1N1c3cc4oc5cc6c(cc5c4cc3B3c4c1cc1c(oc5ccccc51)c4-c1cc(N(c4ccc(C(C)(C)C)cc4)c4ccc(C(C)(C)C)cc4)ccc1N3c1ccc3c(c1)C(C)(C)CCC3(C)C)C(C)(C)CCC6(C)C)C(C)(C)CCC2(C)C] 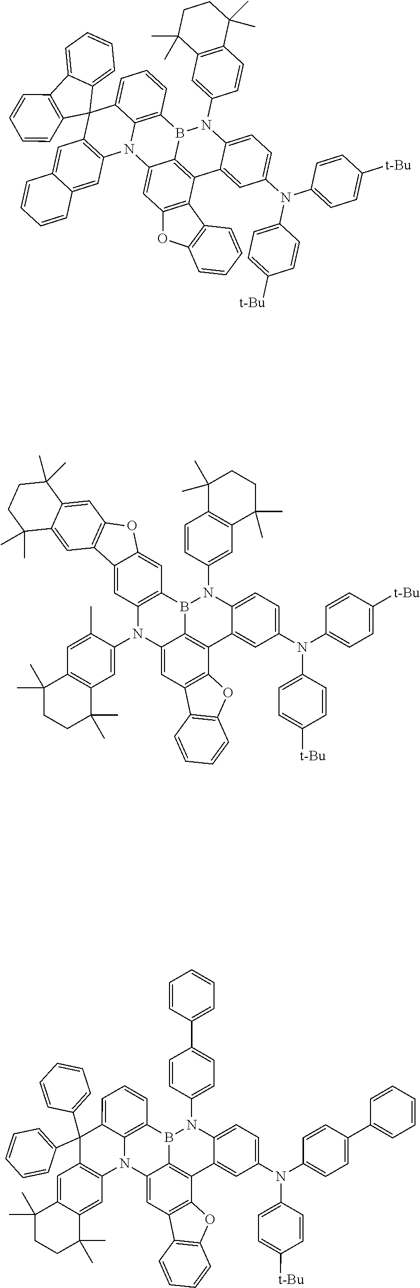 [SMILES: CC(C)(C)c1ccc(N(c2ccc(C(C)(C)C)cc2)c2ccc3c(c2)-c2c4c(cc5oc6ccccc6c25)N2c5cc6ccccc6cc5C5(c6ccccc6-c6ccccc65)c5cccc(c52)B4N3c2ccc3c(c2)C(C)(C)CCC3(C)C)cc1 ; Cc1cc2c(cc1N1c3cc4c(cc3B3c5c1cc1c(oc6ccccc61)c5-c1cc(N(c5ccc(C(C)(C)C)cc5)c5ccc(C(C)(C)C)cc5)ccc1N3c1ccc3c(c1)C(C)(C)CCC3(C)C)oc1cc3c(cc14)C(C)(C)CCC3(C)C)C(C)(C)CCC2(C)C ; CC(C)(C)c1ccc(N(c2ccc(-c3ccccc3)cc2)c2ccc3c(c2)-c2c4c(cc5c2oc2ccccc25)N2c5cc6c(cc5C(c5ccccc5)(c5ccccc5)c5cccc(c52)B4N3c2ccc(-c3ccccc3)cc2)C(C)(C)CCC6(C)C)cc1] 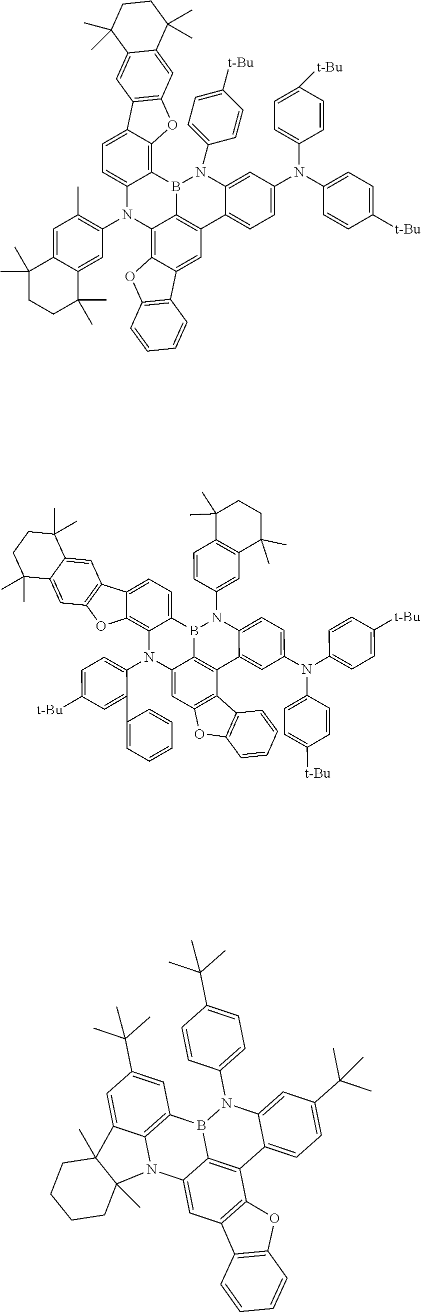 [SMILES: Cc1cc2c(cc1N1c3ccc4c(oc5cc6c(cc54)C(C)(C)CCC6(C)C)c3B3c4c(cc5c(oc6ccccc65)c41)-c1ccc(N(c4ccc(C(C)(C)C)cc4)c4ccc(C(C)(C)C)cc4)cc1N3c1ccc(C(C)(C)C)cc1)C(C)(C)CCC2(C)C ; CC(C)(C)c1ccc(N(c2ccc(C(C)(C)C)cc2)c2ccc3c(c2)-c2c4c(cc5oc6ccccc6c25)N(c2ccc(C(C)(C)C)cc2-c2ccccc2)c2c(ccc5c2oc2cc6c(cc25)C(C)(C)CCC6(C)C)B4N3c2ccc3c(c2)C(C)(C)CCC3(C)C)cc1 ; CC(C)(C)c1ccc(N2B3c4cc(C(C)(C)C)cc5c4N(c4cc6c(oc7ccccc76)c(c43)-c3ccc(C(C)(C)C)cc32)C2(C)CCCCC52C)cc1] 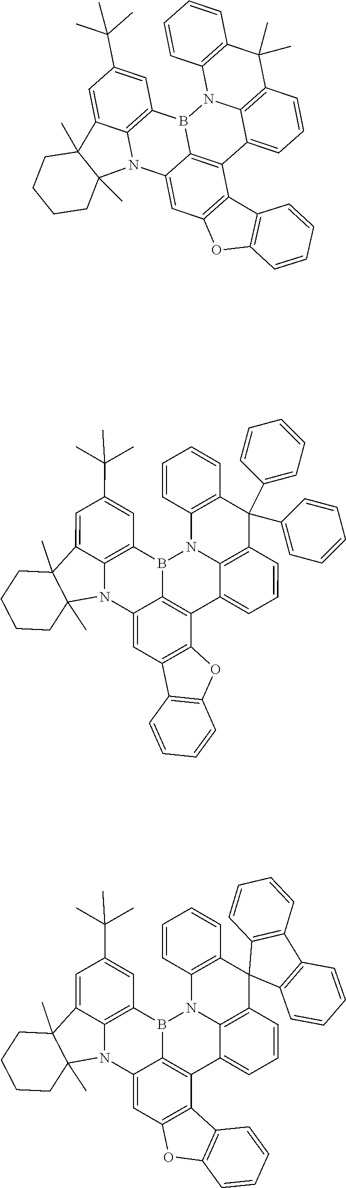 [SMILES: CC(C)(C)c1cc2c3c(c1)C1(C)CCCCC1(C)N3c1cc3oc4ccccc4c3c3c1B2N1c2ccccc2C(C)(C)c2cccc-3c21 ; CC(C)(C)c1cc2c3c(c1)C1(C)CCCCC1(C)N3c1cc3c(oc4ccccc43)c3c1B2N1c2ccccc2C(c2ccccc2)(c2ccccc2)c2cccc-3c21 ; CC(C)(C)c1cc2c3c(c1)C1(C)CCCCC1(C)N3c1cc3oc4ccccc4c3c3c1B2N1c2ccccc2C2(c4ccccc4-c4ccccc42)c2cccc-3c21] 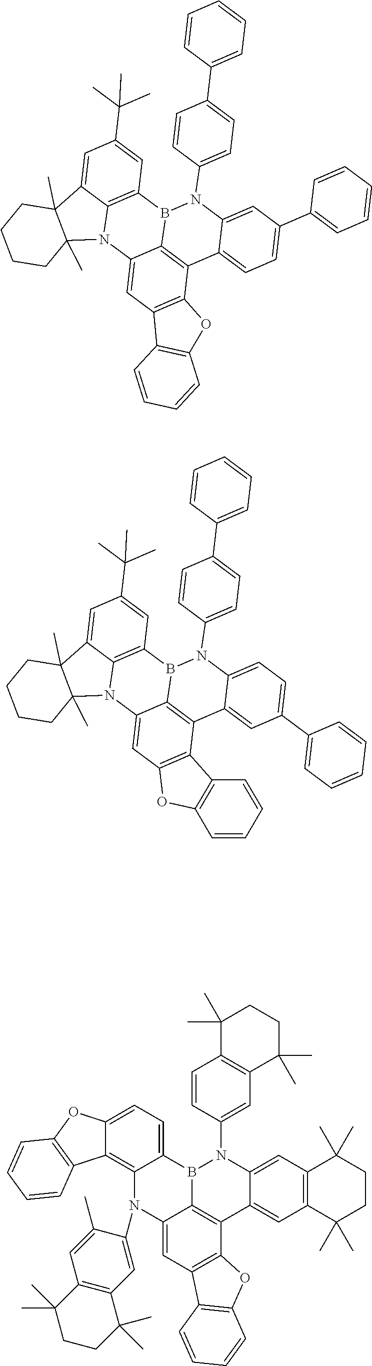 [SMILES: CC(C)(C)c1cc2c3c(c1)C1(C)CCCCC1(C)N3c1cc3c(oc4ccccc43)c3c1B2N(c1ccc(-c2ccccc2)cc1)c1cc(-c2ccccc2)ccc1-3 ; CC(C)(C)c1cc2c3c(c1)C1(C)CCCCC1(C)N3c1cc3oc4ccccc4c3c3c1B2N(c1ccc(-c2ccccc2)cc1)c1ccc(-c2ccccc2)cc1-3 ; Cc1cc2c(cc1N1c3cc4c(oc5ccccc54)c4c3B(c3ccc5oc6ccccc6c5c31)N(c1ccc3c(c1)C(C)(C)CCC3(C)C)c1cc3c(cc1-4)C(C)(C)CCC3(C)C)C(C)(C)CCC2(C)C] 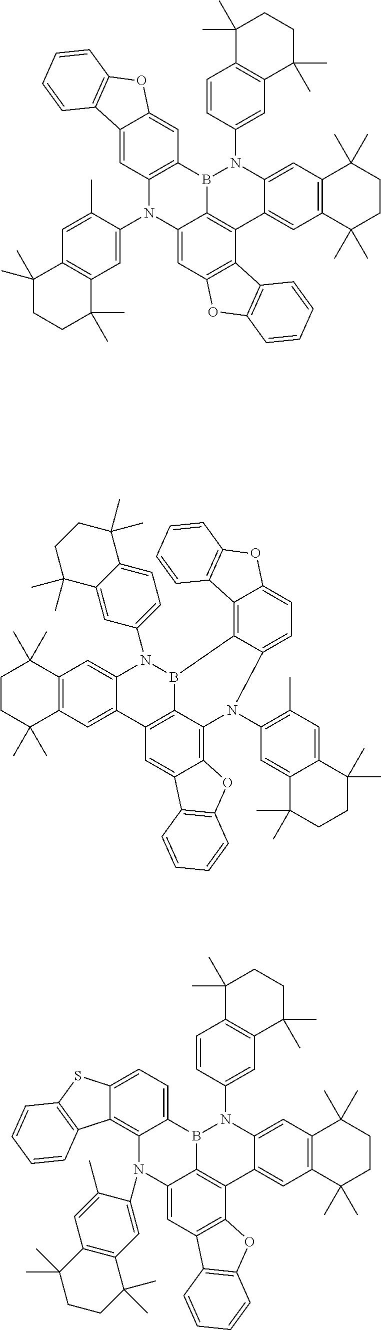 [SMILES: Cc1cc2c(cc1N1c3cc4c(cc3B3c5c1cc1oc6ccccc6c1c5-c1cc5c(cc1N3c1ccc3c(c1)C(C)(C)CCC3(C)C)C(C)(C)CCC5(C)C)oc1ccccc14)C(C)(C)CCC2(C)C ; Cc1cc2c(cc1N1c3ccc4oc5ccccc5c4c3B3c4c(cc5c(oc6ccccc65)c41)-c1cc4c(cc1N3c1ccc3c(c1)C(C)(C)CCC3(C)C)C(C)(C)CCC4(C)C)C(C)(C)CCC2(C)C ; Cc1cc2c(cc1N1c3cc4c(oc5ccccc54)c4c3B(c3ccc5sc6ccccc6c5c31)N(c1ccc3c(c1)C(C)(C)CCC3(C)C)c1cc3c(cc1-4)C(C)(C)CCC3(C)C)C(C)(C)CCC2(C)C] 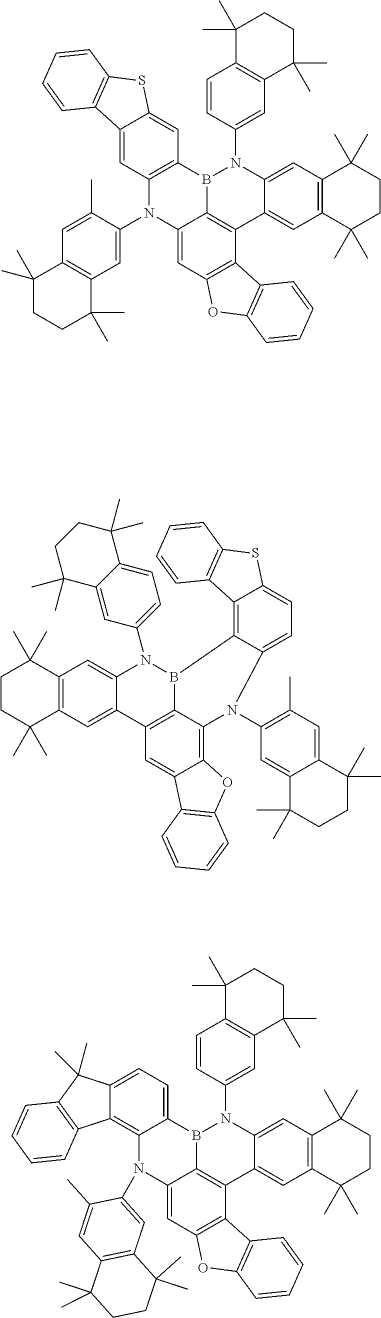 [SMILES: Cc1cc2c(cc1N1c3cc4c(cc3B3c5c1cc1oc6ccccc6c1c5-c1cc5c(cc1N3c1ccc3c(c1)C(C)(C)CCC3(C)C)C(C)(C)CCC5(C)C)sc1ccccc14)C(C)(C)CCC2(C)C ; Cc1cc2c(cc1N1c3ccc4sc5ccccc5c4c3B3c4c(cc5c(oc6ccccc65)c41)-c1cc4c(cc1N3c1ccc3c(c1)C(C)(C)CCC3(C)C)C(C)(C)CCC4(C)C)C(C)(C)CCC2(C)C ; Cc1cc2c(cc1N1c3cc4oc5ccccc5c4c4c3B(c3ccc5c(c31)-c1ccccc1C5(C)C)N(c1ccc3c(c1)C(C)(C)CCC3(C)C)c1cc3c(cc1-4)C(C)(C)CCC3(C)C)C(C)(C)CCC2(C)C] 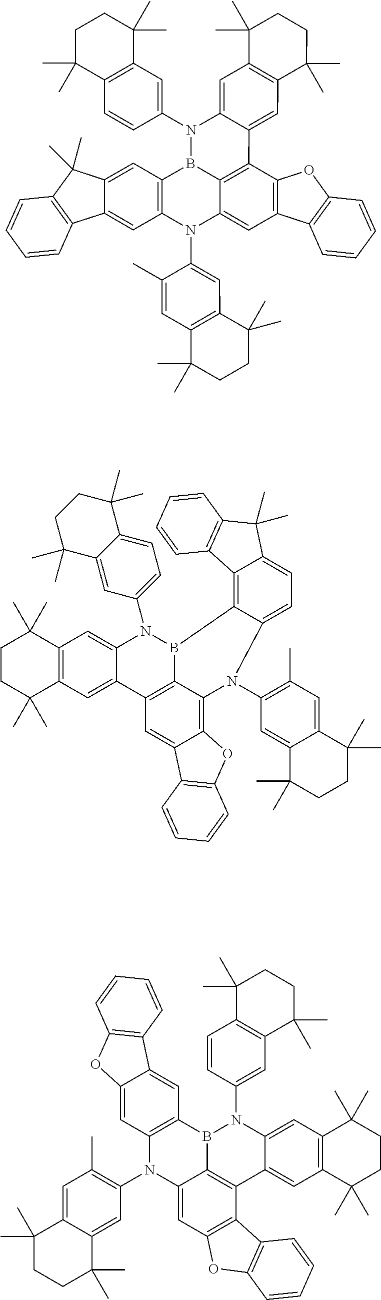 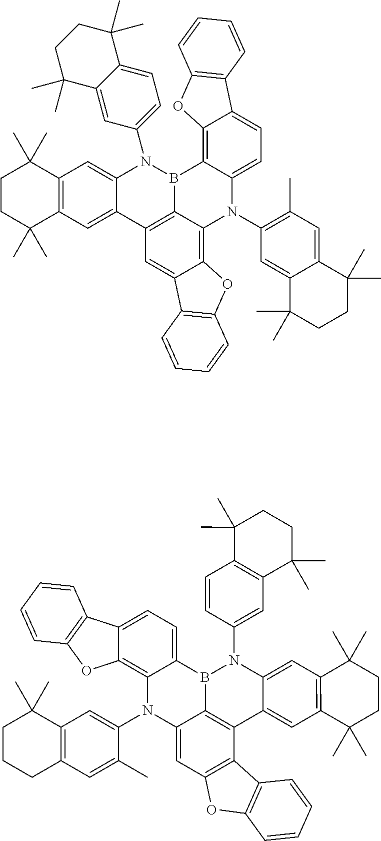 [SMILES: Cc1cc2c(cc1N1c3ccc4c(oc5ccccc54)c3B3c4c(cc5c(oc6ccccc65)c41)-c1cc4c(cc1N3c1ccc3c(c1)C(C)(C)CCC3(C)C)C(C)(C)CCC4(C)C)C(C)(C)CCC2(C)C ; Cc1cc2c(cc1N1c3cc4oc5ccccc5c4c4c3B(c3ccc5c(oc6ccccc65)c31)N(c1ccc3c(c1)C(C)(C)CCC3(C)C)c1cc3c(cc1-4)C(C)(C)CCC3(C)C)C(C)(C)CCC2] 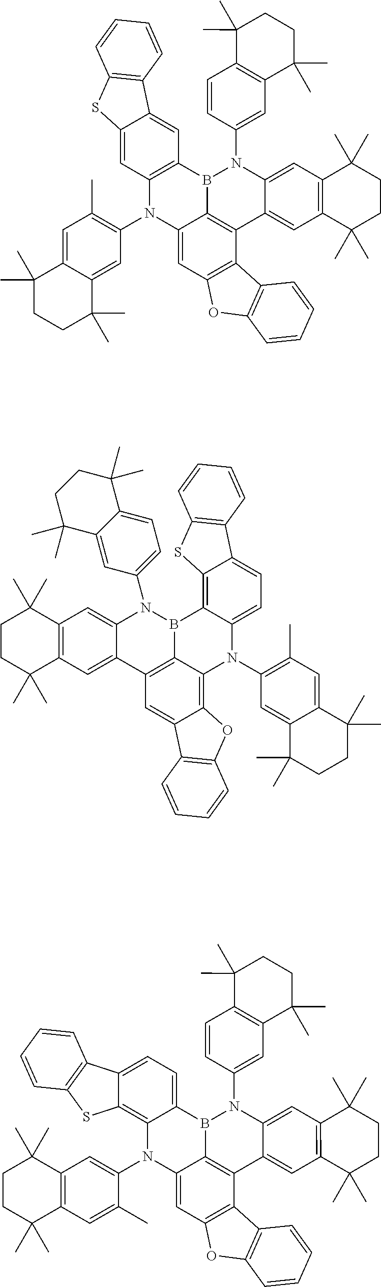 [SMILES: Cc1cc2c(cc1N1c3cc4sc5ccccc5c4cc3B3c4c1cc1oc5ccccc5c1c4-c1cc4c(cc1N3c1ccc3c(c1)C(C)(C)CCC3(C)C)C(C)(C)CCC4(C)C)C(C)(C)CCC2(C)C ; Cc1cc2c(cc1N1c3ccc4c(sc5ccccc54)c3B3c4c(cc5c(oc6ccccc65)c41)-c1cc4c(cc1N3c1ccc3c(c1)C(C)(C)CCC3(C)C)C(C)(C)CCC4(C)C)C(C)(C)CCC2(C)C ; Cc1cc2c(cc1N1c3cc4oc5ccccc5c4c4c3B(c3ccc5c(sc6ccccc65)c31)N(c1ccc3c(c1)C(C)(C)CCC3(C)C)c1cc3c(cc1-4)C(C)(C)CCC3(C)C)C(C)(C)CCC2(C)C] 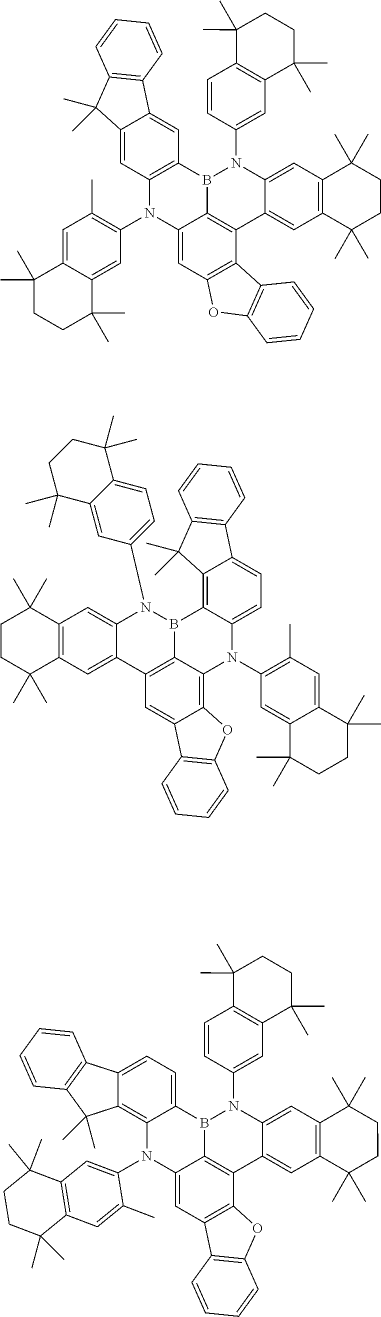 [SMILES: Cc1cc2c(cc1N1c3cc4c(cc3B3c5c1cc1oc6ccccc6c1c5-c1cc5c(cc1N3c1ccc3c(c1)C(C)(C)CCC3(C)C)C(C)(C)CCC5(C)C)-c1ccccc1C4(C)C)C(C)(C)CCC2(C)C ; Cc1cc2c(cc1N1c3ccc4c(c3B3c5c(cc6c(oc7ccccc76)c51)-c1cc5c(cc1N3c1ccc3c(c1)C(C)(C)CCC3(C)C)C(C)(C)CCC5(C)C)C(C)(C)c1ccccc1-4)C(C)(C)CCC2(C)C ; Cc1cc2c(cc1N1c3cc4c(oc5ccccc54)c4c3B(c3ccc5c(c31)C(C)(C)c1ccccc1-5)N(c1ccc3c(c1)C(C)(C)CCC3(C)C)c1cc3c(cc1-4)C(C)(C)CCC3(C)C)C(C)(C)CCC2(C)C] 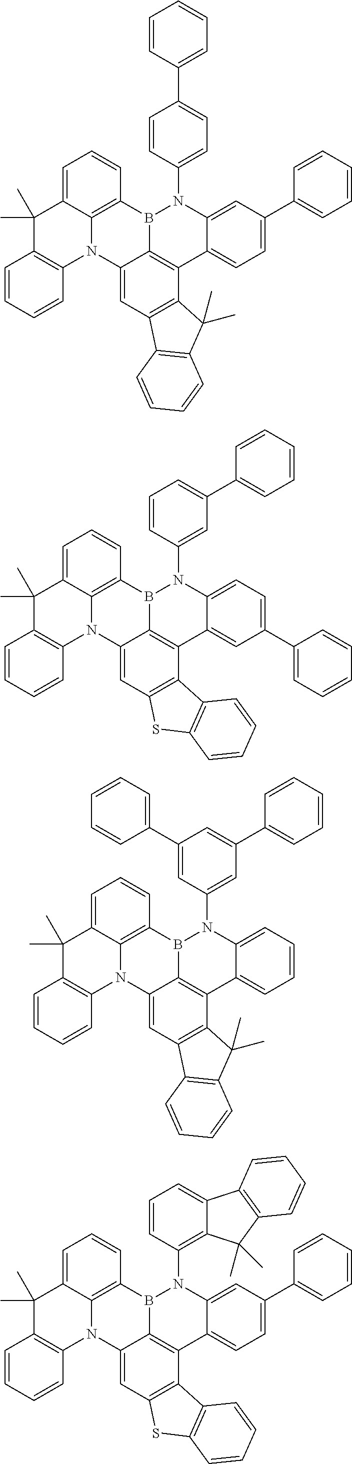 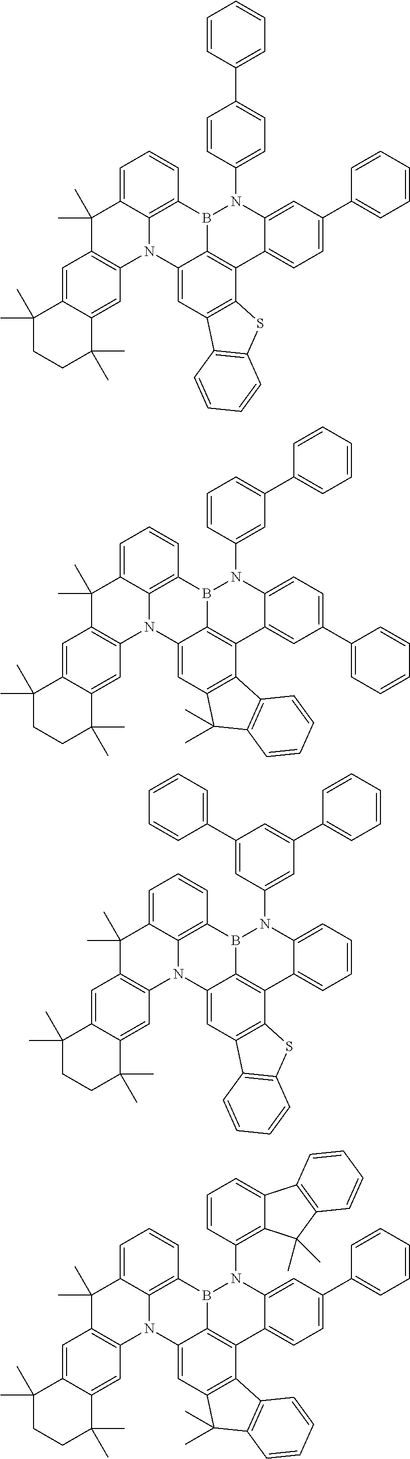 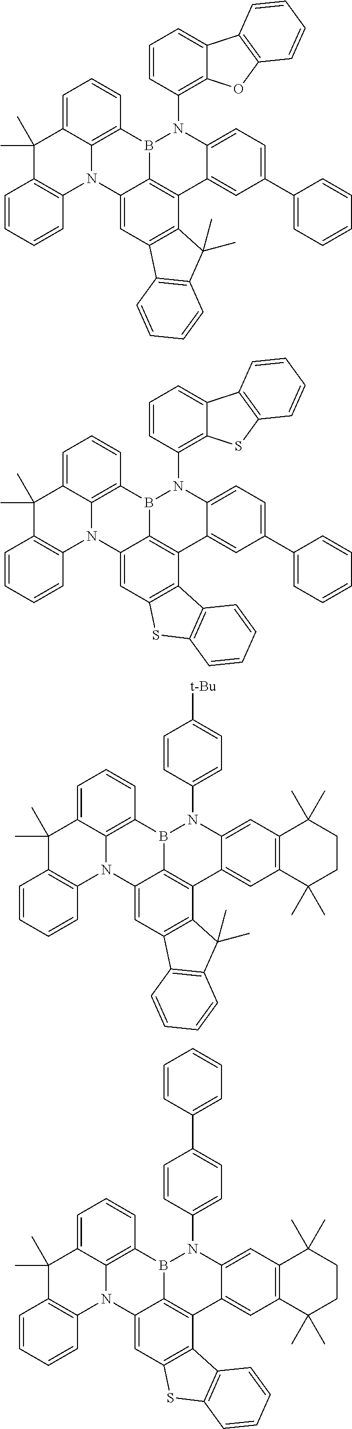 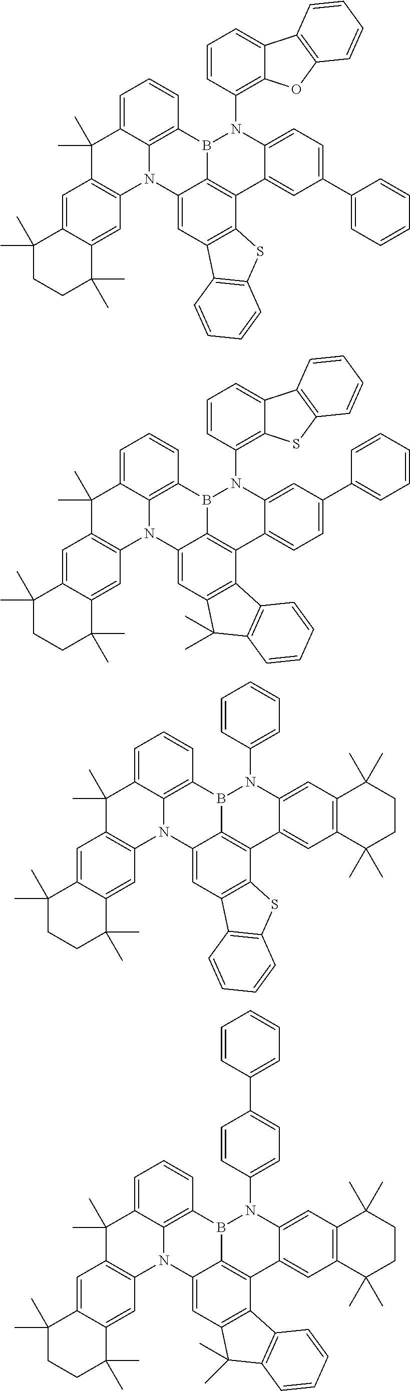 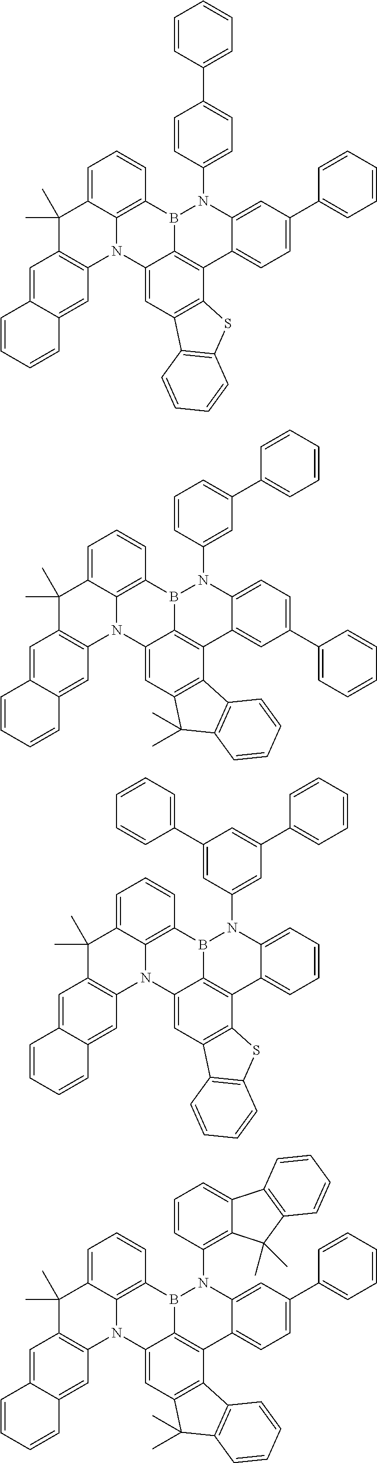 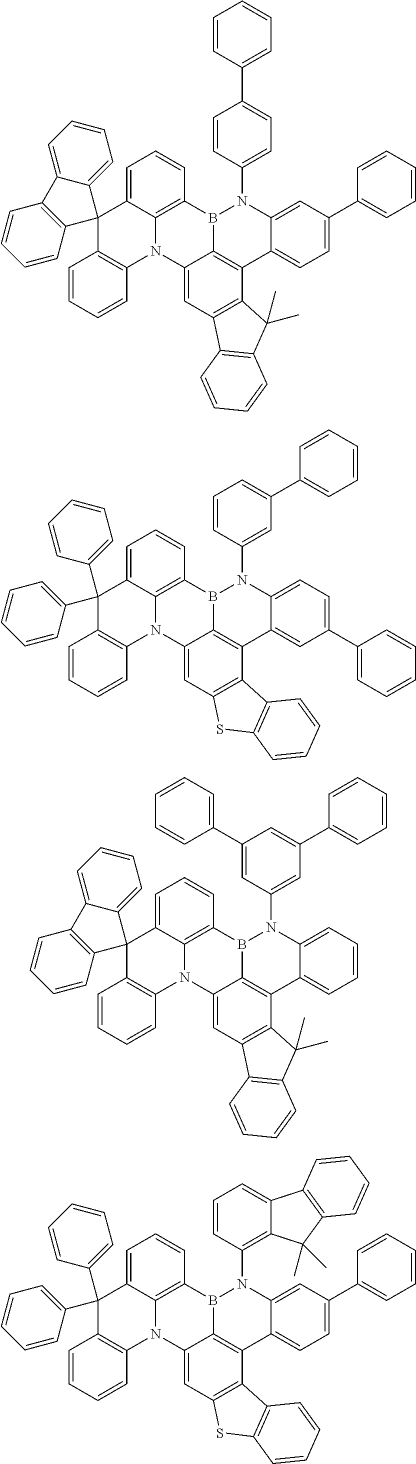 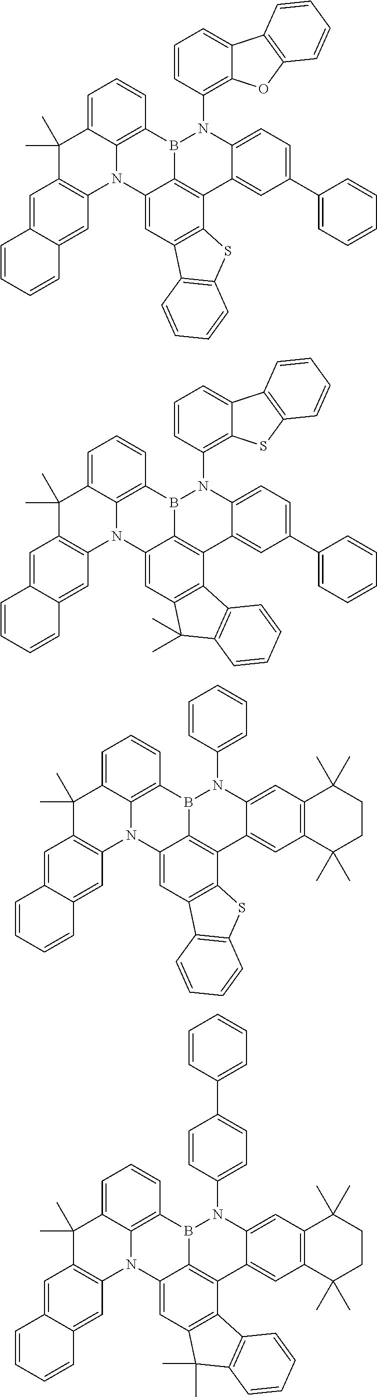 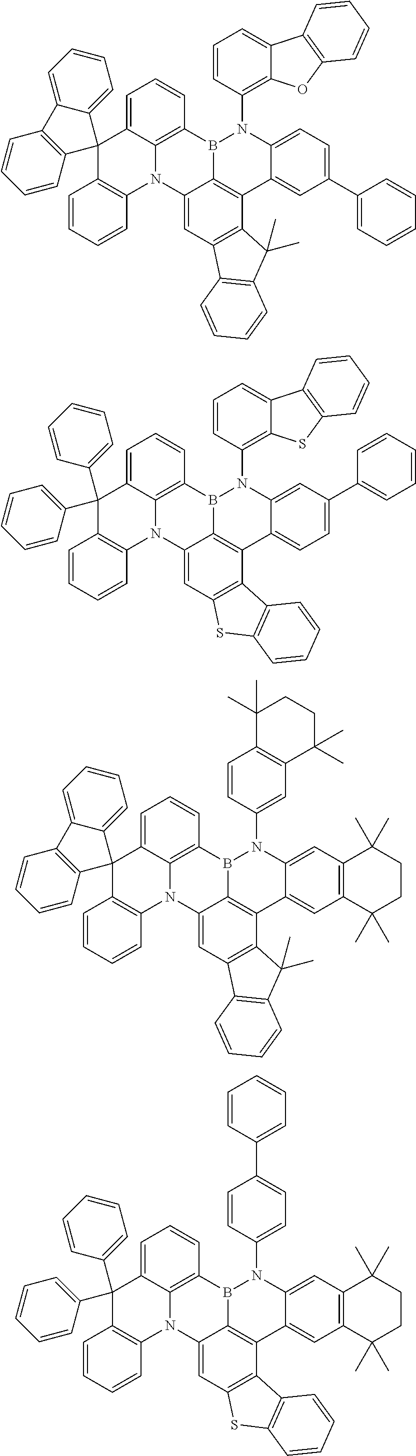 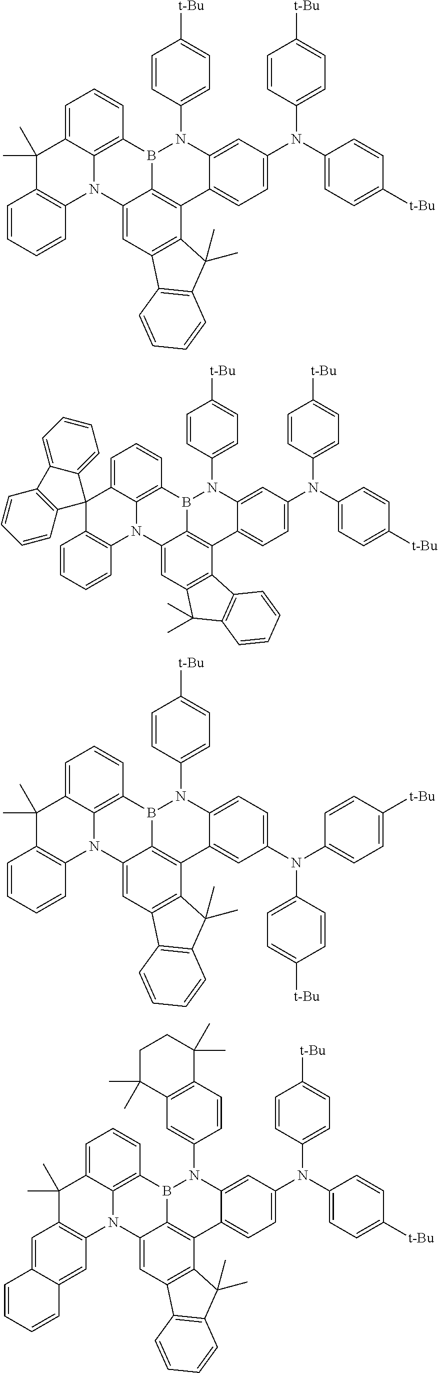 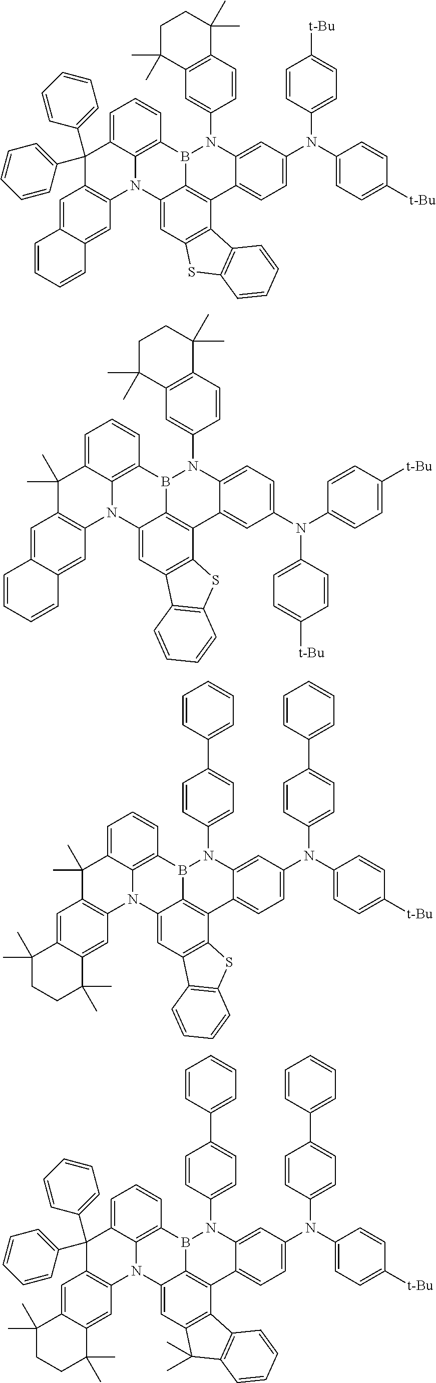 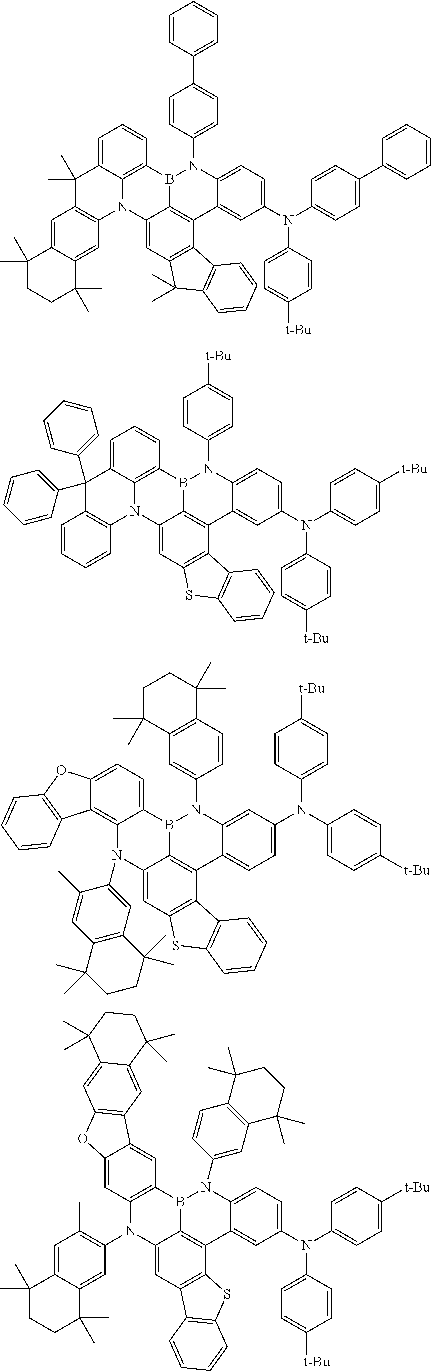 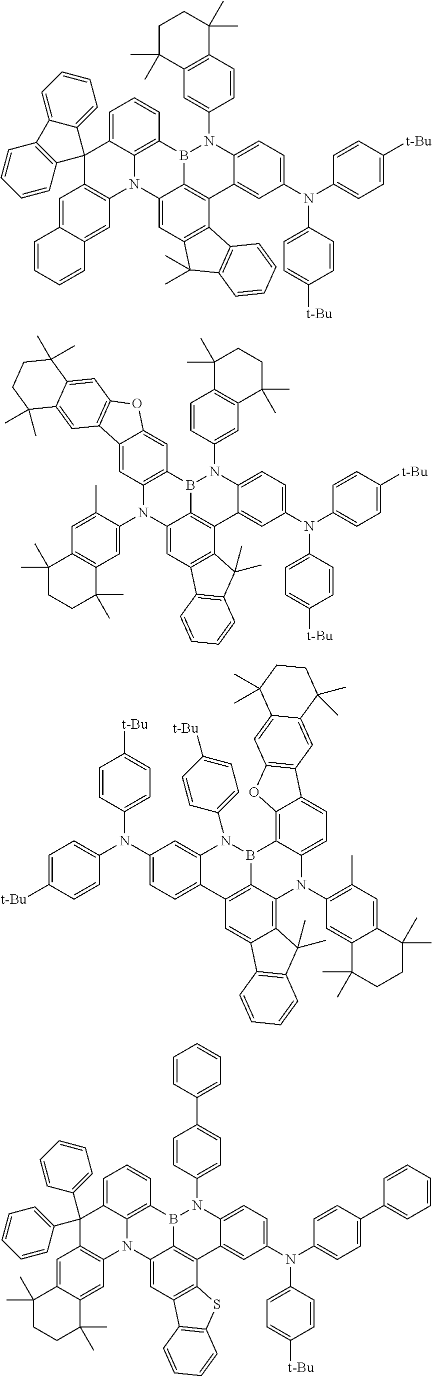 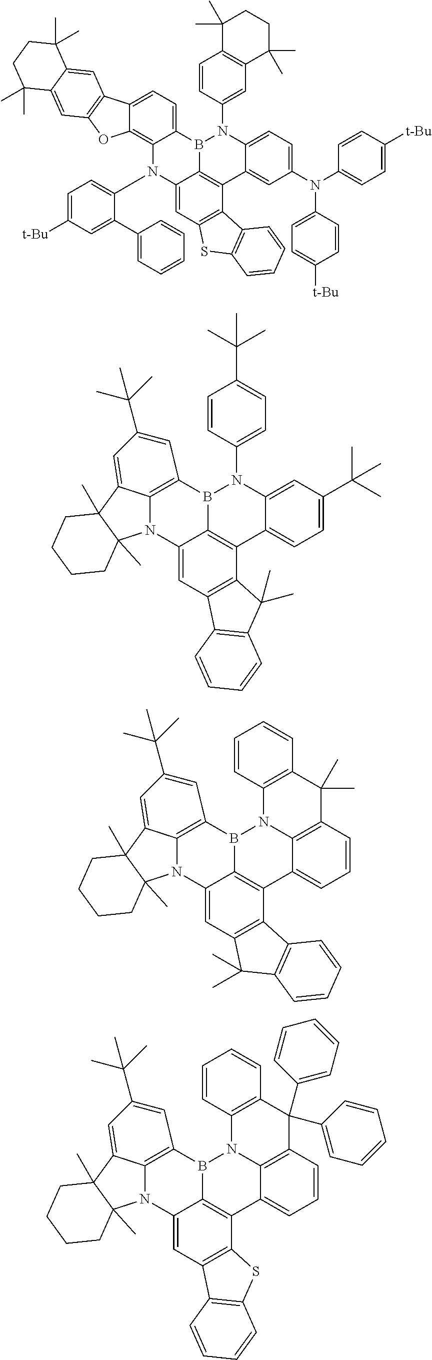 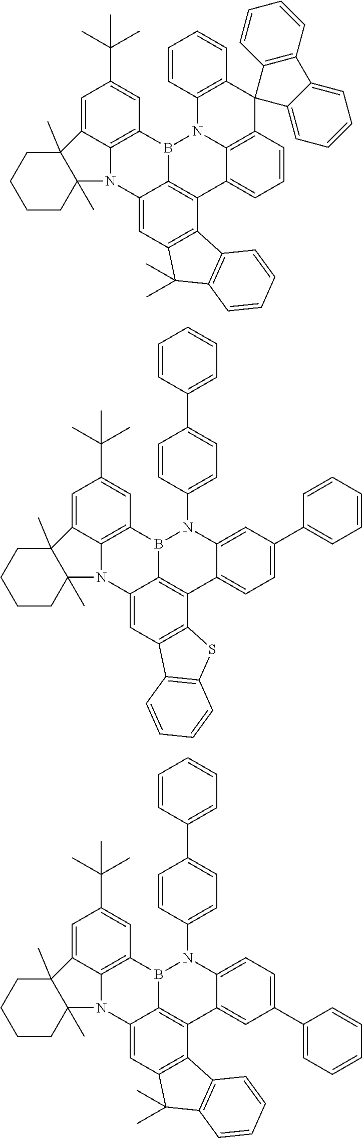 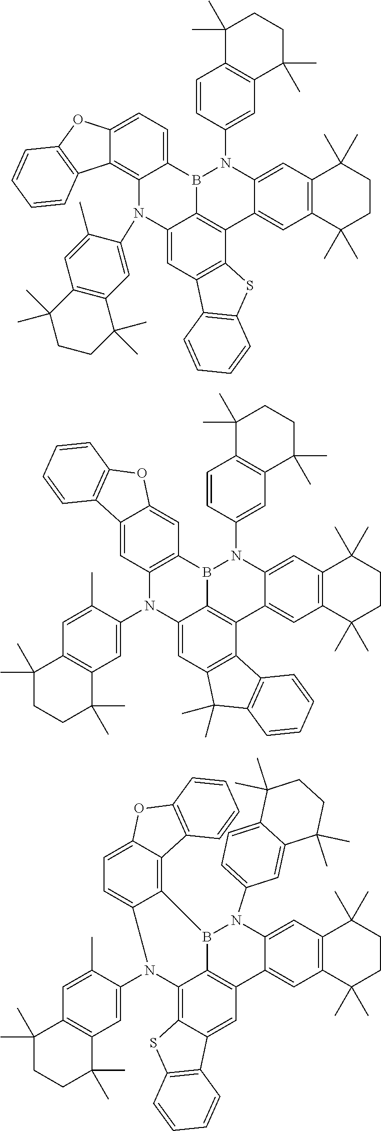 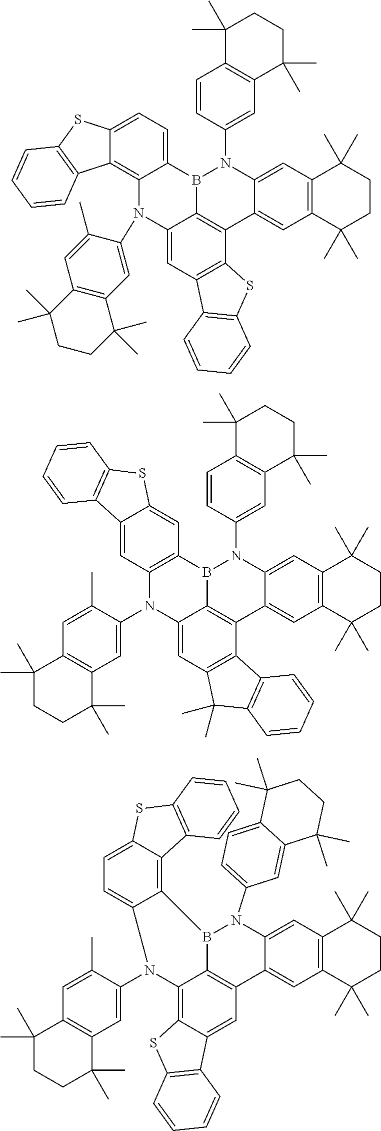 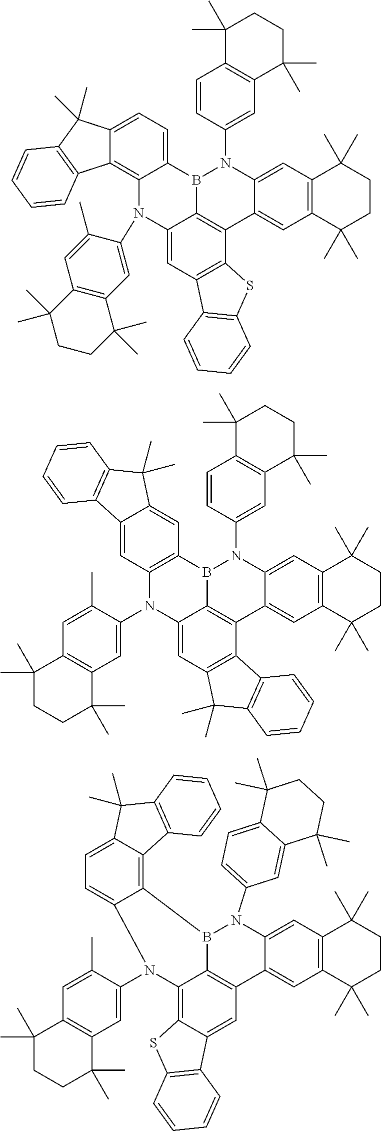 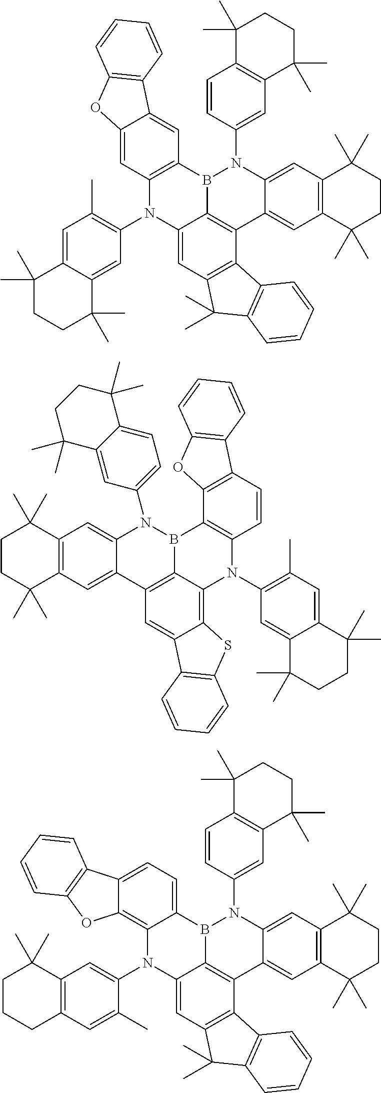 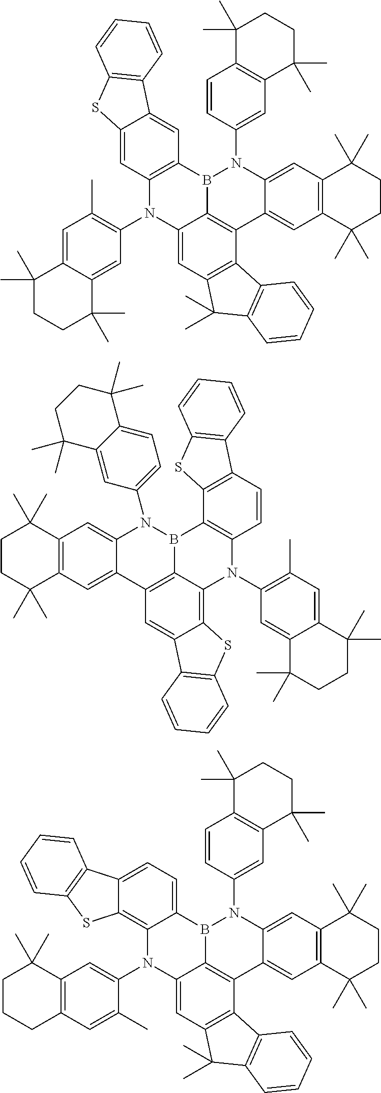 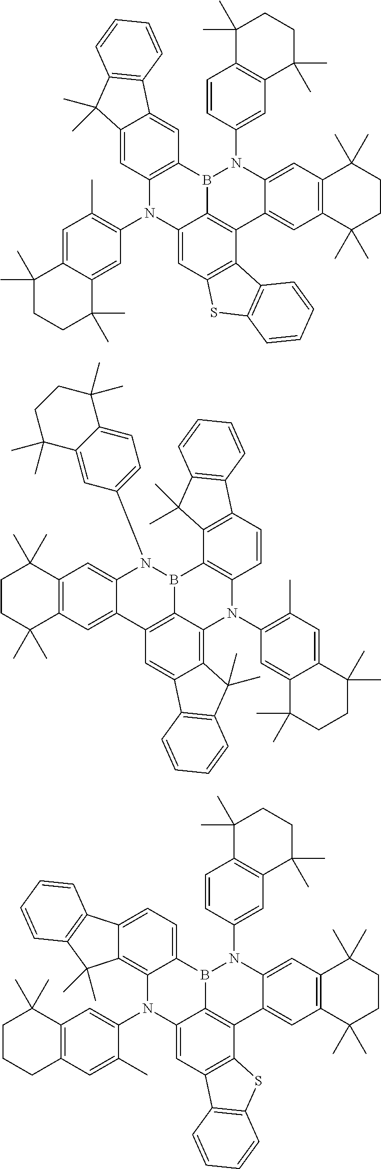 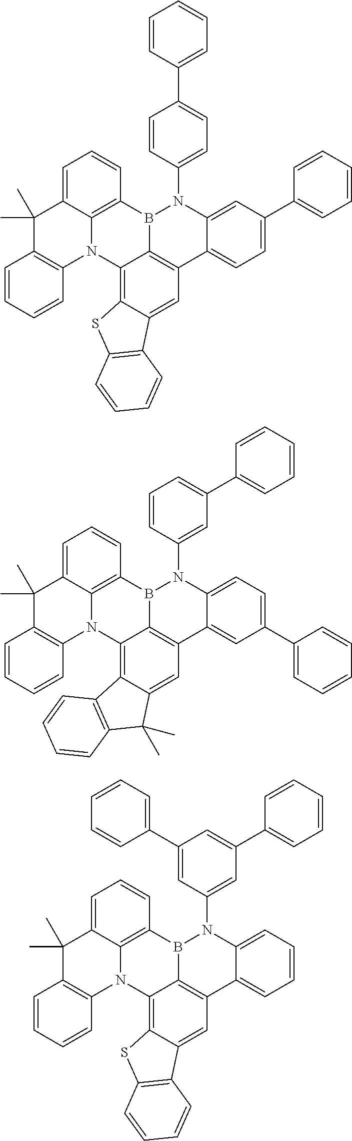 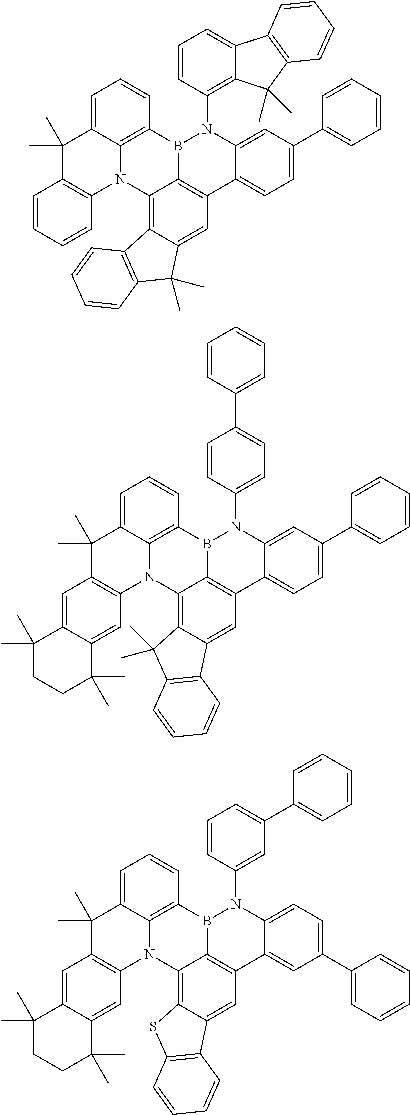 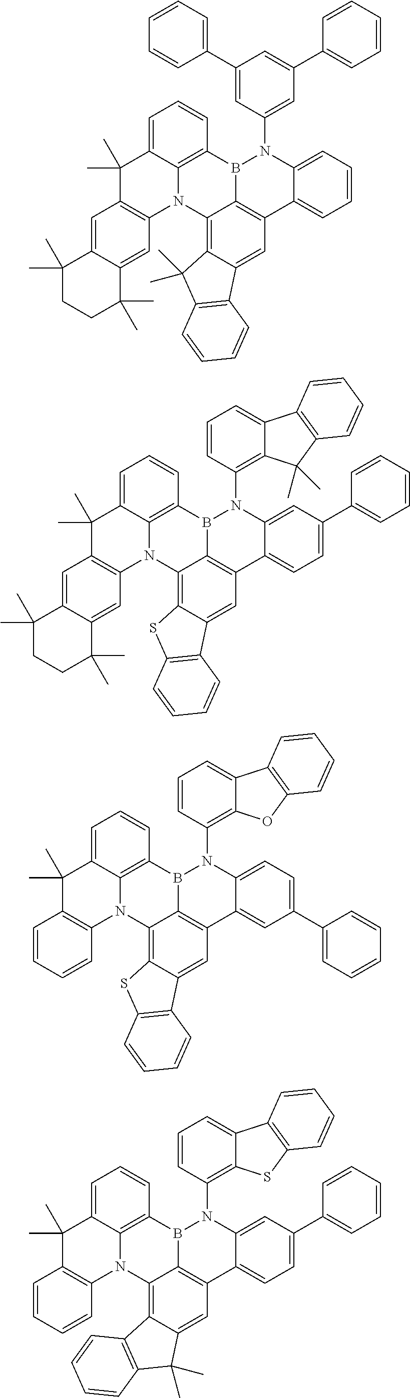 [SMILES: CC1(C)CCC(C)(C)c2cc3c(cc21)N1c2c(cccc2C3(C)C)B2c3c(cc4c(c31)C(C)(C)c1ccccc1-4)-c1ccccc1N2c1cc(-c2ccccc2)cc(-c2ccccc2)c1 ; CC1(C)CCC(C)(C)c2cc3c(cc21)N1c2c(cccc2C3(C)C)B2c3c(cc4c(sc5ccccc54)c31)-c1ccc(-c3ccccc3)cc1N2c1cccc2c1C(C)(C)c1ccccc1-2 ; CC1(C)c2ccccc2N2c3c(cccc31)B1c3c(cc4c(sc5ccccc54)c32)-c2cc(-c3ccccc3)ccc2N1c1cccc2c1oc1ccccc12 ; CC1(C)c2ccccc2-c2c1cc1c3c2N2c4ccccc4C(C)(C)c4cccc(c42)B3N(c2cccc3c2sc2ccccc23)c2cc(-c3ccccc3)ccc2-1] 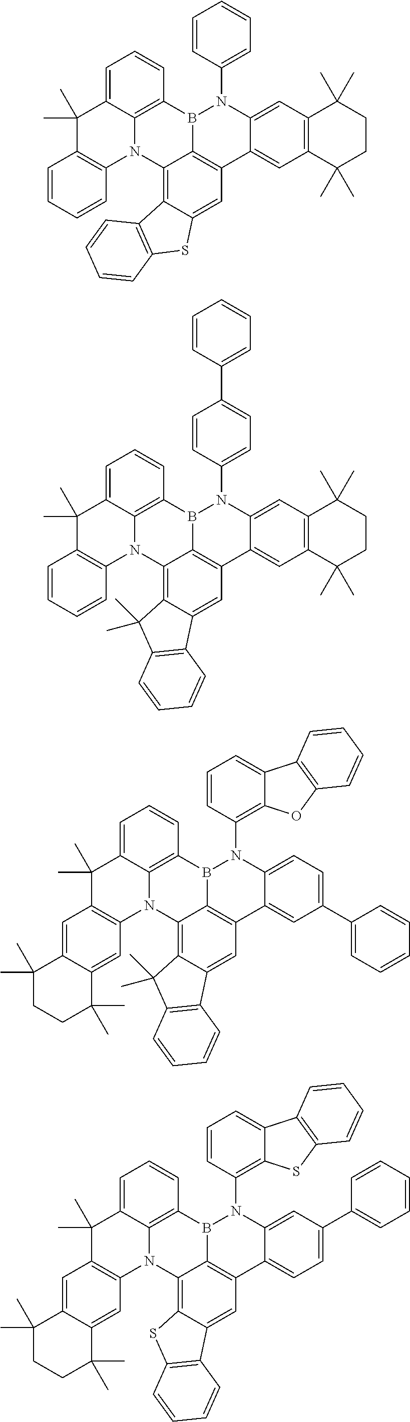 [SMILES: CC1(C)CCC(C)(C)c2cc3c(cc21)-c1cc2sc4ccccc4c2c2c1B(c1cccc4c1N2c1ccccc1C4(C)C)N3c1ccccc1 ; CC1(C)CCC(C)(C)c2cc3c(cc21)-c1cc2c(c4c1B(c1cccc5c1N4c1ccccc1C5(C)C)N3c1ccc(-c3ccccc3)cc1)C(C)(C)c1ccccc1-2 ; CC1(C)CCC(C)(C)c2cc3c(cc21)N1c2c(cccc2C3(C)C)B2c3c(cc4c(c31)C(C)(C)c1ccccc1-4)-c1cc(-c3ccccc3)ccc1N2c1cccc2c1oc1ccccc12 ; CC1(C)CCC(C)(C)c2cc3c(cc21)N1c2c(cccc2C3(C)C)B2c3c(cc4c(sc5ccccc54)c31)-c1ccc(-c3ccccc3)cc1N2c1cccc2c1sc1ccccc12] 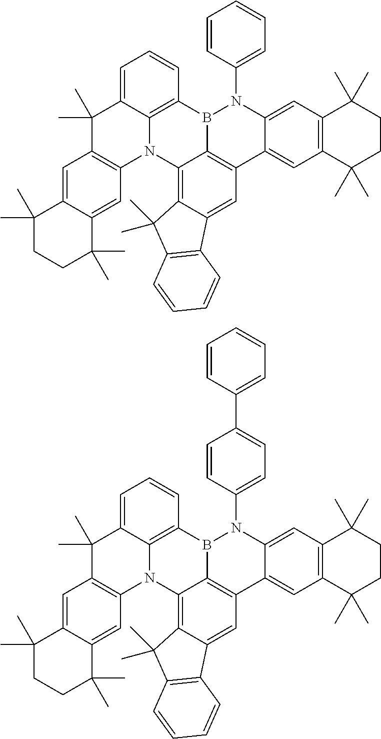 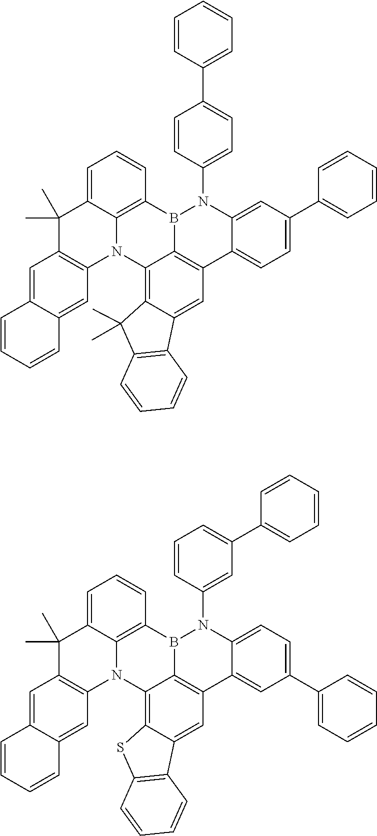 [SMILES: CC1(C)c2cc3ccccc3cc2N2c3c(cccc31)B1c3c(cc4c(c32)C(C)(C)c2ccccc2-4)-c2ccc(-c3ccccc3)cc2N1c1ccc(-c2ccccc2)cc1 ; CC1(C)c2cc3ccccc3cc2N2c3c(cccc31)B1c3c(cc4c(sc5ccccc54)c32)-c2cc(-c3ccccc3)ccc2N1c1cccc(-c2ccccc2)c1] 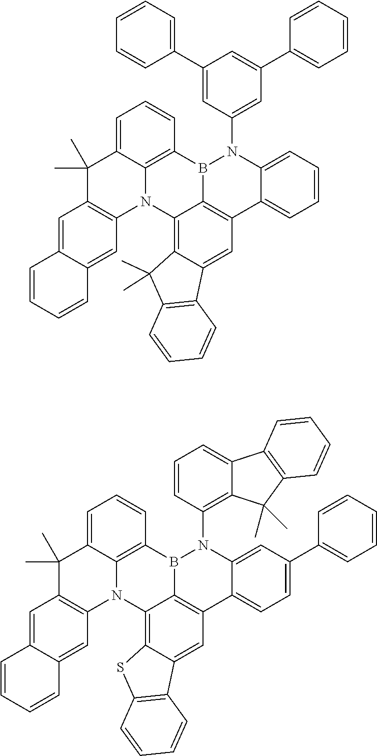 [SMILES: CC1(C)c2cc3ccccc3cc2N2c3c(cccc31)B1c3c(cc4c(c32)C(C)(C)c2ccccc2-4)-c2ccccc2N1c1cc(-c2ccccc2)cc(-c2ccccc2)c1 ; CC1(C)c2cc3ccccc3cc2N2c3c(cccc31)B1c3c(cc4c(sc5ccccc54)c32)-c2ccc(-c3ccccc3)cc2N1c1cccc2c1C(C)(C)c1ccccc1-2] 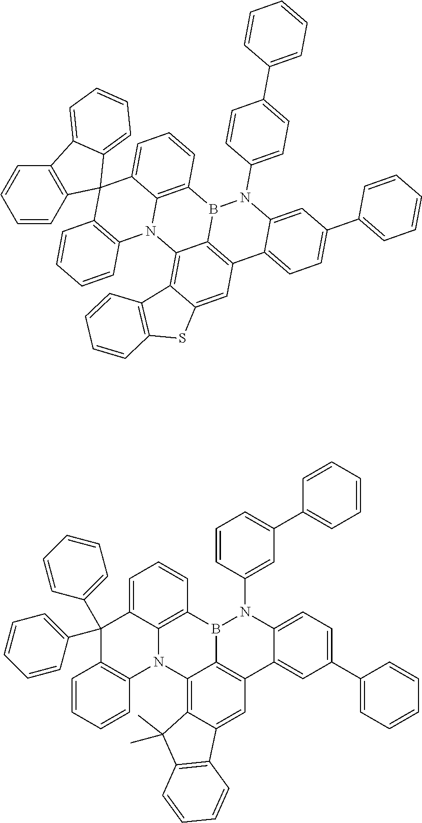 [SMILES: c1ccc(-c2ccc(N3B4c5cccc6c5N(c5ccccc5C65c6ccccc6-c6ccccc65)c5c4c(cc4sc6ccccc6c54)-c4ccc(-c5ccccc5)cc43)cc2)cc1 ; CC1(C)c2ccccc2-c2cc3c4c(c21)N1c2ccccc2C(c2ccccc2)(c2ccccc2)c2cccc(c21)B4N(c1cccc(-c2ccccc2)c1)c1ccc(-c2ccccc2)cc1-3] 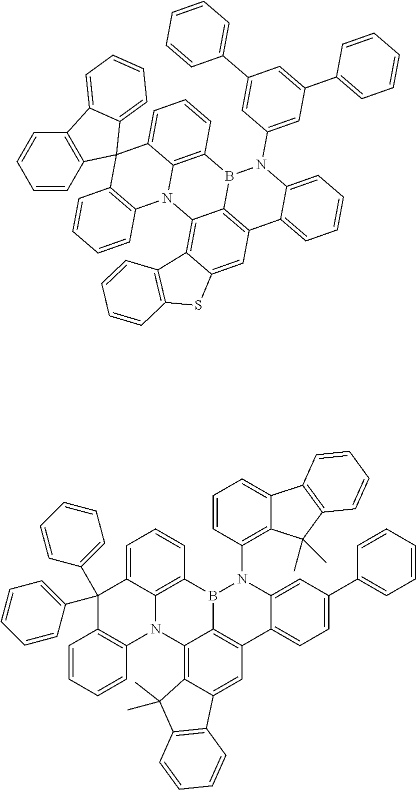 [SMILES: c1ccc(-c2cc(-c3ccccc3)cc(N3B4c5cccc6c5N(c5ccccc5C65c6ccccc6-c6ccccc65)c5c4c(cc4sc6ccccc6c54)-c4ccccc43)c2)cc1 ; CC1(C)c2ccccc2-c2cccc(N3B4c5cccc6c5N(c5ccccc5C6(c5ccccc5)c5ccccc5)c5c4c(cc4c5C(C)(C)c5ccccc5-4)-c4ccc(-c5ccccc5)cc43)c21] 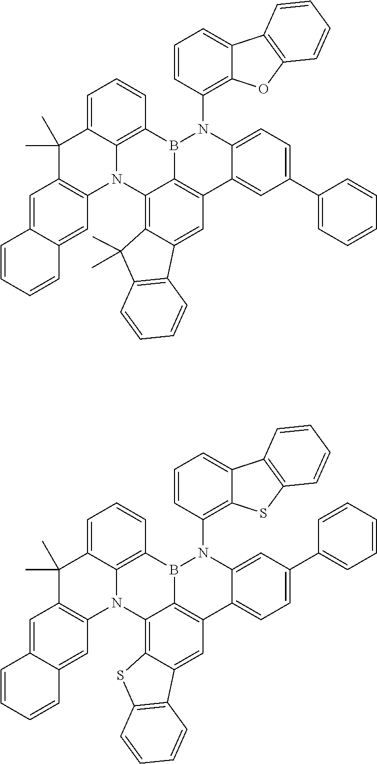 [SMILES: CC1(C)c2cc3ccccc3cc2N2c3c(cccc31)B1c3c(cc4c(c32)C(C)(C)c2ccccc2-4)-c2cc(-c3ccccc3)ccc2N1c1cccc2c1oc1ccccc12 ; CC1(C)c2cc3ccccc3cc2N2c3c(cccc31)B1c3c(cc4c(sc5ccccc54)c32)-c2ccc(-c3ccccc3)cc2N1c1cccc2c1sc1ccccc12] 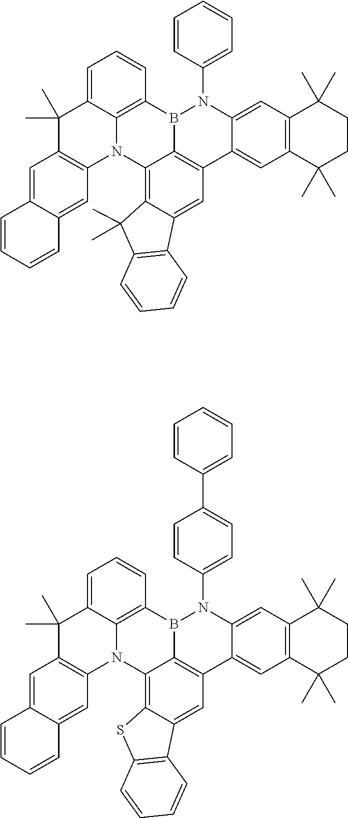 [SMILES: CC1(C)CCC(C)(C)c2cc3c(cc21)-c1cc2c(c4c1B(c1cccc5c1N4c1cc4ccccc4cc1C5(C)C)N3c1ccccc1)C(C)(C)c1ccccc1-2 ; CC1(C)CCC(C)(C)c2cc3c(cc21)-c1cc2c(sc4ccccc42)c2c1B(c1cccc4c1N2c1cc2ccccc2cc1C4(C)C)N3c1ccc(-c2ccccc2)cc1] 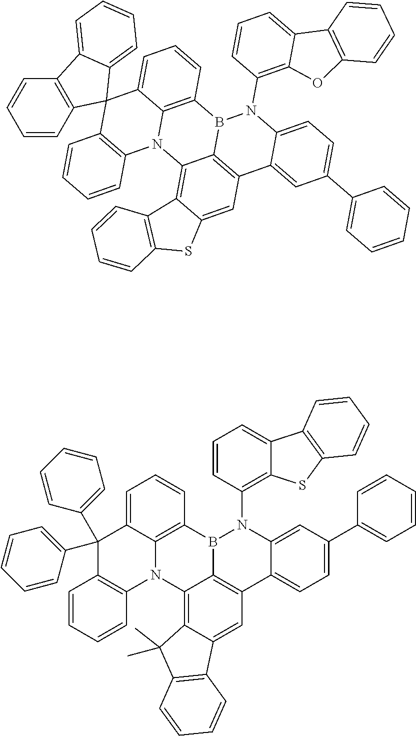 [SMILES: c1ccc(-c2ccc3c(c2)-c2cc4sc5ccccc5c4c4c2B(c2cccc5c2N4c2ccccc2C52c4ccccc4-c4ccccc42)N3c2cccc3c2oc2ccccc23)cc1 ; CC1(C)c2ccccc2-c2cc3c4c(c21)N1c2ccccc2C(c2ccccc2)(c2ccccc2)c2cccc(c21)B4N(c1cccc2c1sc1ccccc12)c1cc(-c2ccccc2)ccc1-3] 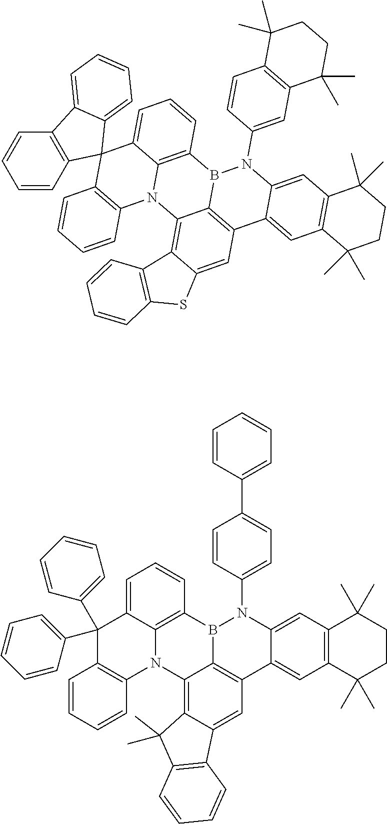 [SMILES: CC1(C)CCC(C)(C)c2cc(N3B4c5cccc6c5N(c5ccccc5C65c6ccccc6-c6ccccc65)c5c4c(cc4sc6ccccc6c54)-c4cc5c(cc43)C(C)(C)CCC5(C)C)ccc21 ; CC1(C)CCC(C)(C)c2cc3c(cc21)-c1cc2c(c4c1B(c1cccc5c1N4c1ccccc1C5(c1ccccc1)c1ccccc1)N3c1ccc(-c3ccccc3)cc1)C(C)(C)c1ccccc1-2] 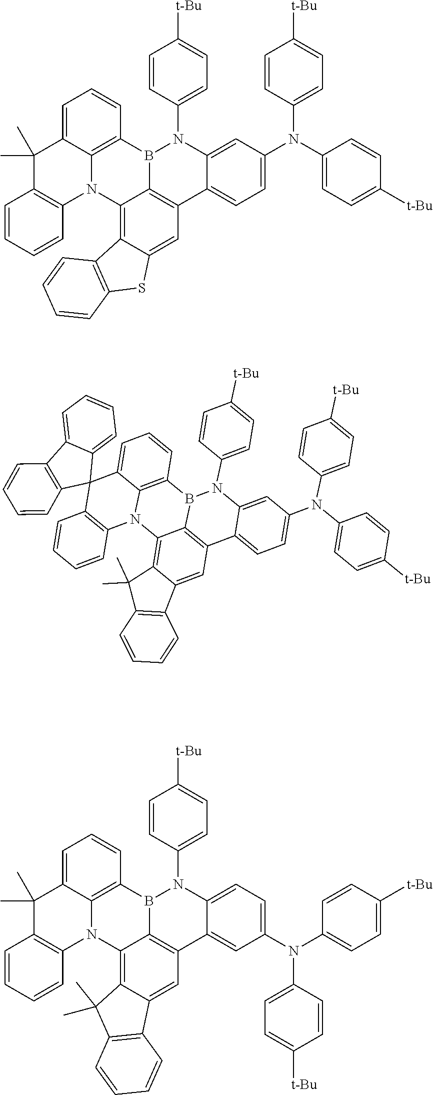 [SMILES: CC(C)(C)c1ccc(N2B3c4cccc5c4N(c4ccccc4C5(C)C)c4c3c(cc3sc5ccccc5c43)-c3ccc(N(c4ccc(C(C)(C)C)cc4)c4ccc(C(C)(C)C)cc4)cc32)cc1 ; CC(C)(C)c1ccc(N2B3c4cccc5c4N(c4ccccc4C54c5ccccc5-c5ccccc54)c4c3c(cc3c4C(C)(C)c4ccccc4-3)-c3ccc(N(c4ccc(C(C)(C)C)cc4)c4ccc(C(C)(C)C)cc4)cc32)cc1 ; CC(C)(C)c1ccc(N2B3c4cccc5c4N(c4ccccc4C5(C)C)c4c3c(cc3c4C(C)(C)c4ccccc4-3)-c3cc(N(c4ccc(C(C)(C)C)cc4)c4ccc(C(C)(C)C)cc4)ccc32)cc1] 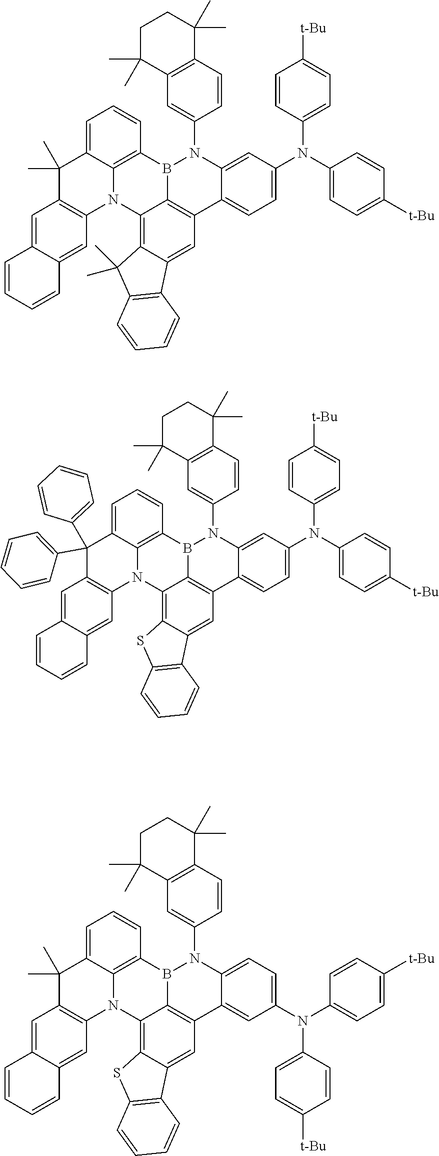 [SMILES: CC(C)(C)c1ccc(N(c2ccc(C(C)(C)C)cc2)c2ccc3c(c2)N(c2ccc4c(c2)C(C)(C)CCC4(C)C)B2c4cccc5c4N(c4cc6ccccc6cc4C5(C)C)c4c2c-3cc2c4C(C)(C)c3ccccc3-2)cc1 ; CC(C)(C)c1ccc(N(c2ccc(C(C)(C)C)cc2)c2ccc3c(c2)N(c2ccc4c(c2)C(C)(C)CCC4(C)C)B2c4cccc5c4N(c4cc6ccccc6cc4C5(c4ccccc4)c4ccccc4)c4c2c-3cc2c4sc3ccccc32)cc1 ; CC(C)(C)c1ccc(N(c2ccc(C(C)(C)C)cc2)c2ccc3c(c2)-c2cc4c(sc5ccccc54)c4c2B(c2cccc5c2N4c2cc4ccccc4cc2C5(C)C)N3c2ccc3c(c2)C(C)(C)CCC3(C)C)cc1] 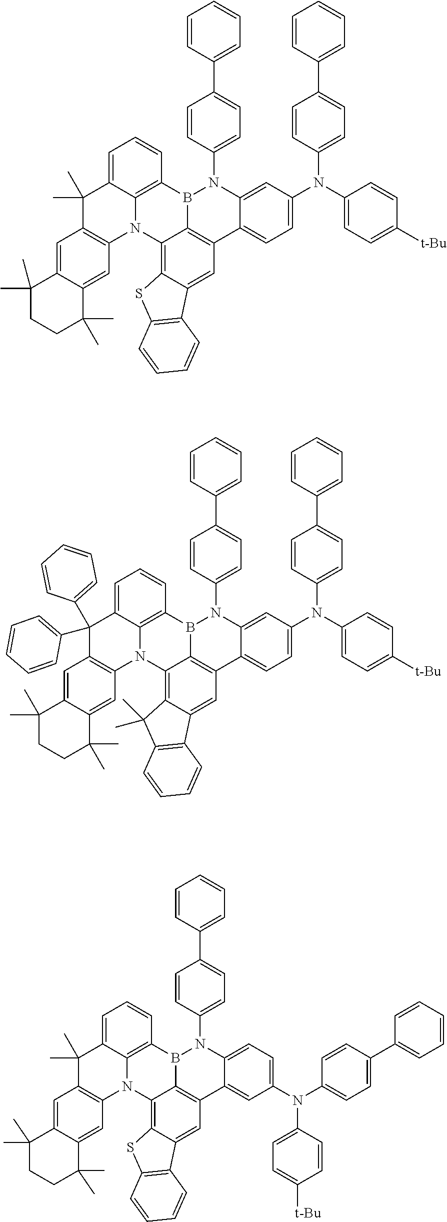 [SMILES: CC(C)(C)c1ccc(N(c2ccc(-c3ccccc3)cc2)c2ccc3c(c2)N(c2ccc(-c4ccccc4)cc2)B2c4cccc5c4N(c4cc6c(cc4C5(C)C)C(C)(C)CCC6(C)C)c4c2c-3cc2c4sc3ccccc32)cc1 ; CC(C)(C)c1ccc(N(c2ccc(-c3ccccc3)cc2)c2ccc3c(c2)N(c2ccc(-c4ccccc4)cc2)B2c4cccc5c4N(c4cc6c(cc4C5(c4ccccc4)c4ccccc4)C(C)(C)CCC6(C)C)c4c2c-3cc2c4C(C)(C)c3ccccc3-2)cc1 ; CC(C)(C)c1ccc(N(c2ccc(-c3ccccc3)cc2)c2ccc3c(c2)-c2cc4c(sc5ccccc54)c4c2B(c2cccc5c2N4c2cc4c(cc2C5(C)C)C(C)(C)CCC4(C)C)N3c2ccc(-c3ccccc3)cc2)cc1] 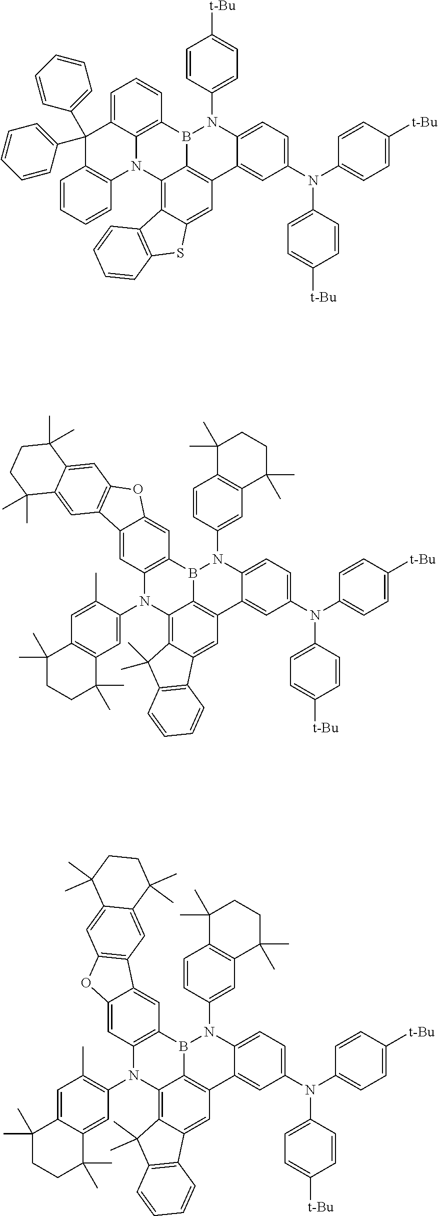 [SMILES: CC(C)(C)c1ccc(N2B3c4cccc5c4N(c4ccccc4C5(c4ccccc4)c4ccccc4)c4c3c(cc3sc5ccccc5c43)-c3cc(N(c4ccc(C(C)(C)C)cc4)c4ccc(C(C)(C)C)cc4)ccc32)cc1 ; Cc1cc2c(cc1N1c3cc4c(cc3B3c5c(cc6c(c51)C(C)(C)c1ccccc1-6)-c1cc(N(c5ccc(C(C)(C)C)cc5)c5ccc(C(C)(C)C)cc5)ccc1N3c1ccc3c(c1)C(C)(C)CCC3(C)C)oc1cc3c(cc14)C(C)(C)CCC3(C)C)C(C)(C)CCC2(C)C ; Cc1cc2c(cc1N1c3cc4oc5cc6c(cc5c4cc3B3c4c(cc5c(c41)C(C)(C)c1ccccc1-5)-c1cc(N(c4ccc(C(C)(C)C)cc4)c4ccc(C(C)(C)C)cc4)ccc1N3c1ccc3c(c1)C(C)(C)CCC3(C)C)C(C)(C)CCC6(C)C)C(C)(C)CCC2(C)C] 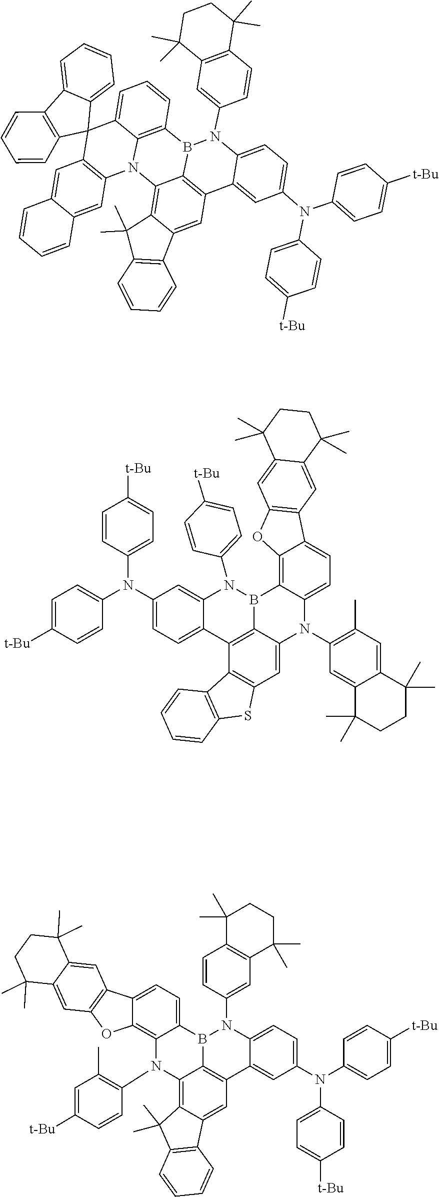 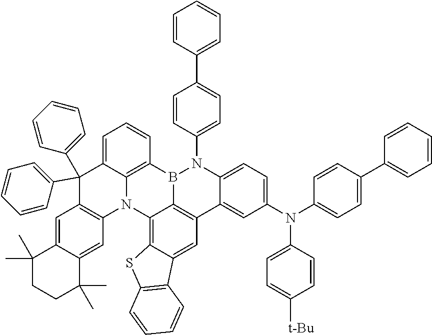 [SMILES: CC(C)(C)c1ccc(N(c2ccc(-c3ccccc3)cc2)c2ccc3c(c2)-c2cc4c(sc5ccccc54)c4c2B(c2cccc5c2N4c2cc4c(cc2C5(c2ccccc2)c2ccccc2)C(C)(C)CCC4(C)C)N3c2ccc(-c3ccccc3)cc2)cc1] 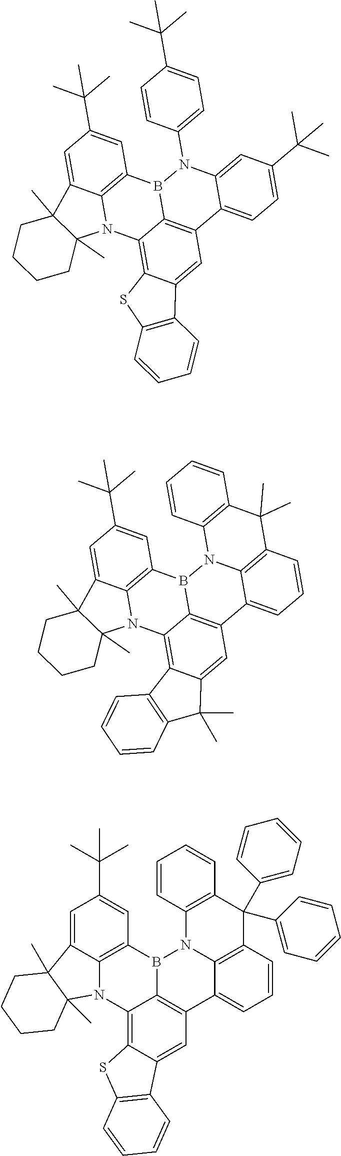 [SMILES: CC(C)(C)c1ccc(N2B3c4cc(C(C)(C)C)cc5c4N(c4c3c(cc3c4sc4ccccc43)-c3ccc(C(C)(C)C)cc32)C2(C)CCCCC52C)cc1 ; CC(C)(C)c1cc2c3c(c1)C1(C)CCCCC1(C)N3c1c3c(cc4c1-c1ccccc1C4(C)C)-c1cccc4c1N(B23)c1ccccc1C4(C)C ; CC(C)(C)c1cc2c3c(c1)C1(C)CCCCC1(C)N3c1c3c(cc4c1sc1ccccc14)-c1cccc4c1N(B23)c1ccccc1C4(c1ccccc1)c1ccccc1] 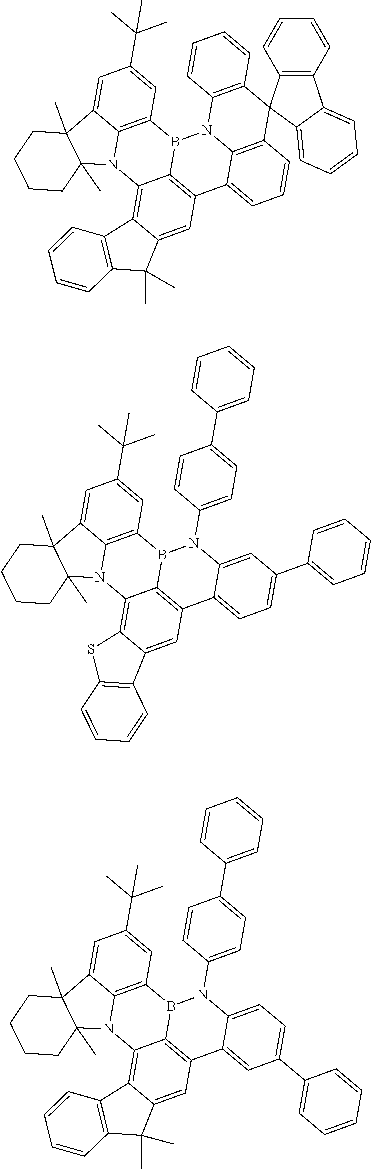 [SMILES: CC(C)(C)c1cc2c3c(c1)C1(C)CCCCC1(C)N3c1c3c(cc4c1-c1ccccc1C4(C)C)-c1cccc4c1N(B23)c1ccccc1C41c2ccccc2-c2ccccc21 ; CC(C)(C)c1cc2c3c(c1)C1(C)CCCCC1(C)N3c1c3c(cc4c1sc1ccccc14)-c1ccc(-c4ccccc4)cc1N(c1ccc(-c4ccccc4)cc1)B23 ; CC(C)(C)c1cc2c3c(c1)C1(C)CCCCC1(C)N3c1c3c(cc4c1-c1ccccc1C4(C)C)-c1cc(-c4ccccc4)ccc1N(c1ccc(-c4ccccc4)cc1)B23] 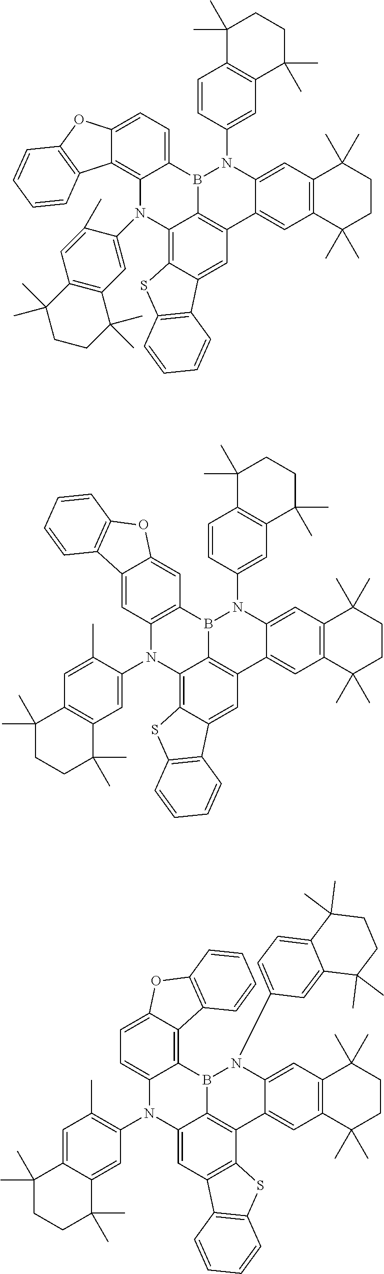 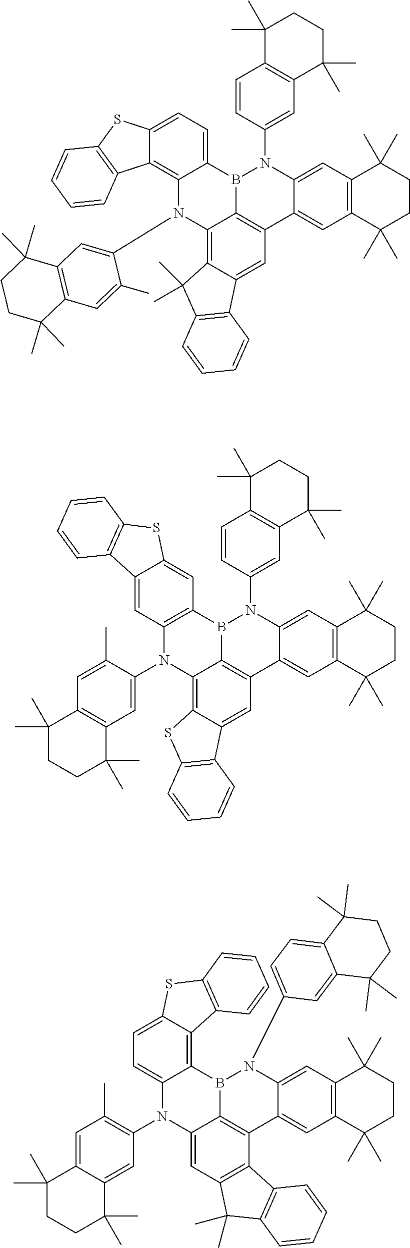 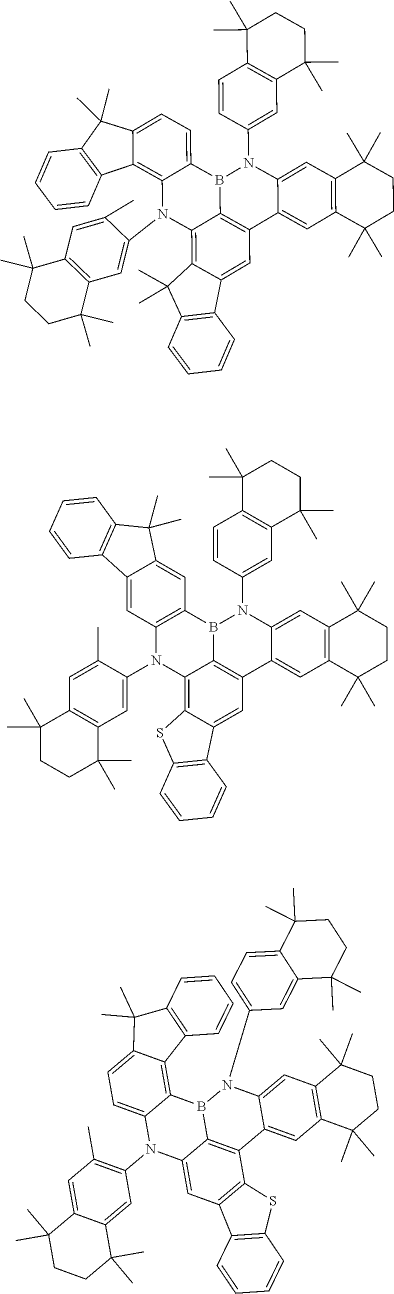 [SMILES: Cc1cc2c(cc1N1c3c(ccc4c3-c3ccccc3C4(C)C)B3c4c(cc5c(c41)C(C)(C)c1ccccc1-5)-c1cc4c(cc1N3c1ccc3c(c1)C(C)(C)CCC3(C)C)C(C)(C)CCC4(C)C)C(C)(C)CCC2(C)C ; Cc1cc2c(cc1N1c3cc4c(cc3B3c5c(cc6c(sc7ccccc76)c51)-c1cc5c(cc1N3c1ccc3c(c1)C(C)(C)CCC3(C)C)C(C)(C)CCC5(C)C)C(C)(C)c1ccccc1-4)C(C)(C)CCC2(C)C ; Cc1cc2c(cc1N1c3ccc4c(c3B3c5c1cc1c(sc6ccccc61)c5-c1cc5c(cc1N3c1ccc3c(c1)C(C)(C)CCC3(C)C)C(C)(C)CCC5(C)C)-c1ccccc1C4(C)C)C(C)(C)CCC2(C)C] 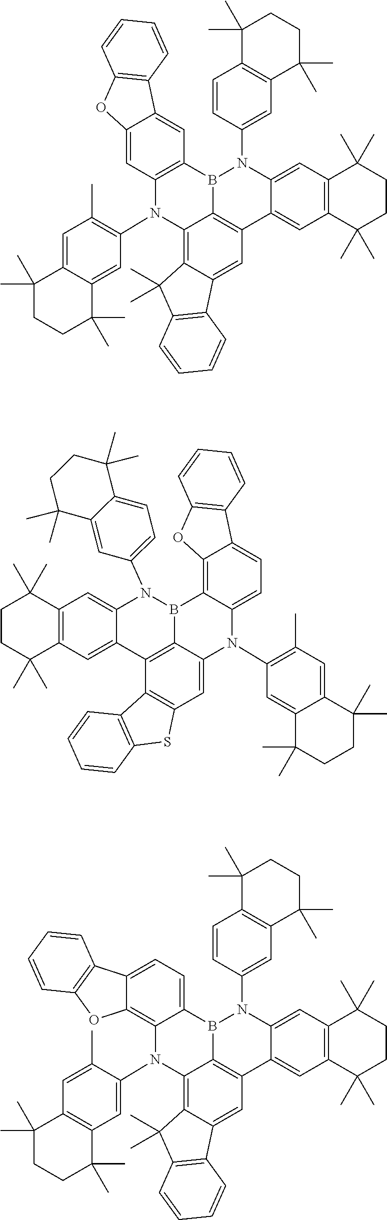 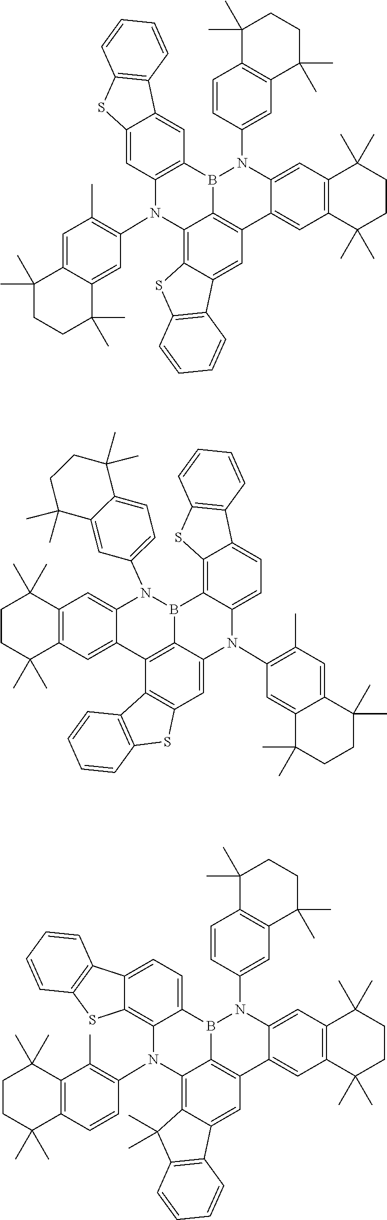 [SMILES: Cc1cc2c(cc1N1c3cc4sc5ccccc5c4cc3B3c4c(cc5c(sc6ccccc65)c41)-c1cc4c(cc1N3c1ccc3c(c1)C(C)(C)CCC3(C)C)C(C)(C)CCC4(C)C)C(C)(C)CCC2(C)C ; Cc1cc2c(cc1N1c3cc4sc5ccccc5c4c4c3B(c3c1ccc1c3sc3ccccc31)N(c1ccc3c(c1)C(C)(C)CCC3(C)C)c1cc3c(cc1-4)C(C)(C)CCC3(C)C)C(C)(C)CCC2(C)C ; Cc1c(N2c3c4c(cc5c3C(C)(C)c3ccccc3-5)-c3cc5c(cc3N(c3ccc6c(c3)C(C)(C)CCC6(C)C)B4c3ccc4c(sc6ccccc64)c32)C(C)(C)CCC5(C)C)ccc2c1C(C)(C)CCC2(C)C] 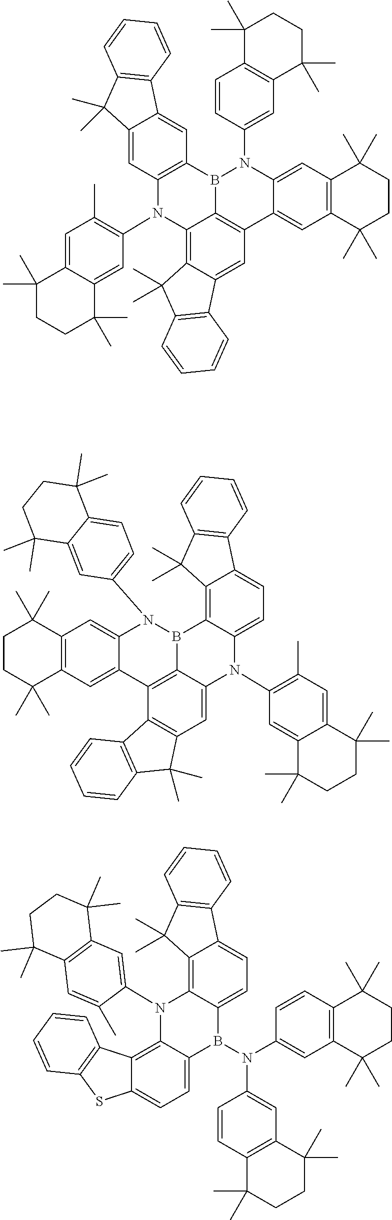 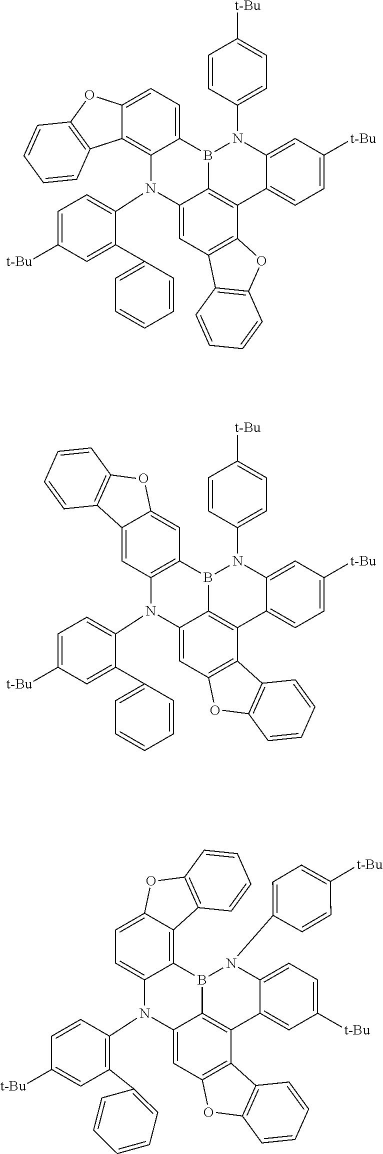 [SMILES: CC(C)(C)c1ccc(N2B3c4ccc5oc6ccccc6c5c4N(c4ccc(C(C)(C)C)cc4-c4ccccc4)c4cc5c(oc6ccccc65)c(c43)-c3ccc(C(C)(C)C)cc32)cc1 ; CC(C)(C)c1ccc(N2B3c4cc5oc6ccccc6c5cc4N(c4ccc(C(C)(C)C)cc4-c4ccccc4)c4cc5oc6ccccc6c5c(c43)-c3ccc(C(C)(C)C)cc32)cc1 ; CC(C)(C)c1ccc(N2B3c4c(cc5oc6ccccc6c5c4-c4cc(C(C)(C)C)ccc42)N(c2ccc(C(C)(C)C)cc2-c2ccccc2)c2ccc4oc5ccccc5c4c23)cc1] 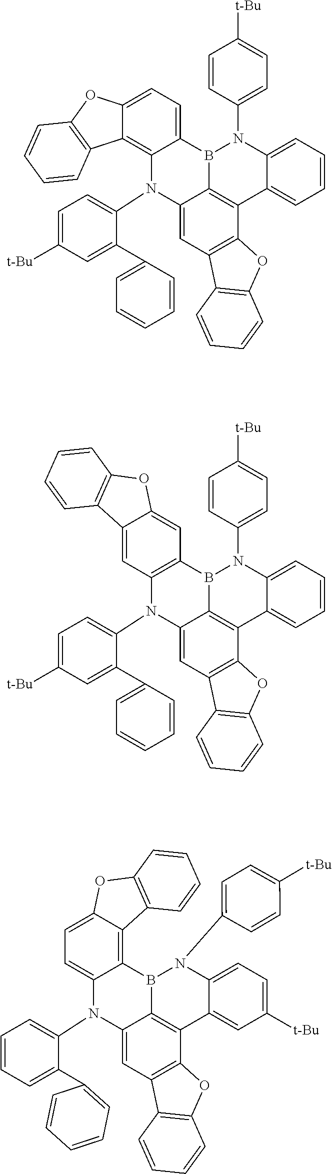 [SMILES: CC(C)(C)c1ccc(N2B3c4ccc5oc6ccccc6c5c4N(c4ccc(C(C)(C)C)cc4-c4ccccc4)c4cc5c(oc6ccccc65)c(c43)-c3ccccc32)cc1 ; CC(C)(C)c1ccc(N2B3c4cc5oc6ccccc6c5cc4N(c4ccc(C(C)(C)C)cc4-c4ccccc4)c4cc5c(oc6ccccc65)c(c43)-c3ccccc32)cc1 ; CC(C)(C)c1ccc(N2B3c4c(cc5c(oc6ccccc65)c4-c4cc(C(C)(C)C)ccc42)N(c2ccccc2-c2ccccc2)c2ccc4oc5ccccc5c4c23)cc1] 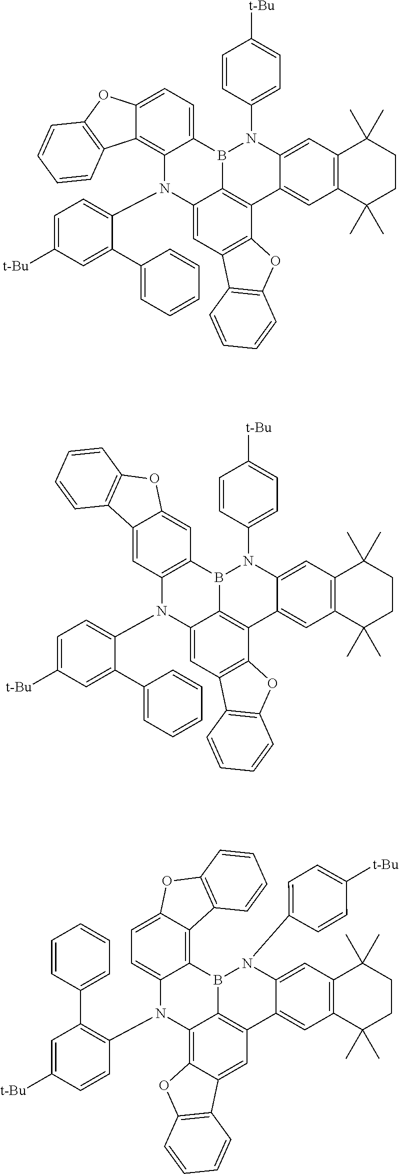 [SMILES: CC(C)(C)c1ccc(N2B3c4ccc5oc6ccccc6c5c4N(c4ccc(C(C)(C)C)cc4-c4ccccc4)c4cc5c(oc6ccccc65)c(c43)-c3cc4c(cc32)C(C)(C)CCC4(C)C)cc1 ; CC(C)(C)c1ccc(N2B3c4cc5oc6ccccc6c5cc4N(c4ccc(C(C)(C)C)cc4-c4ccccc4)c4cc5c(oc6ccccc65)c(c43)-c3cc4c(cc32)C(C)(C)CCC4(C)C)cc1 ; CC(C)(C)c1ccc(N2B3c4c(cc5c(oc6ccccc65)c4N(c4ccc(C(C)(C)C)cc4-c4ccccc4)c4ccc5oc6ccccc6c5c43)-c3cc4c(cc32)C(C)(C)CCC4(C)C)cc1] 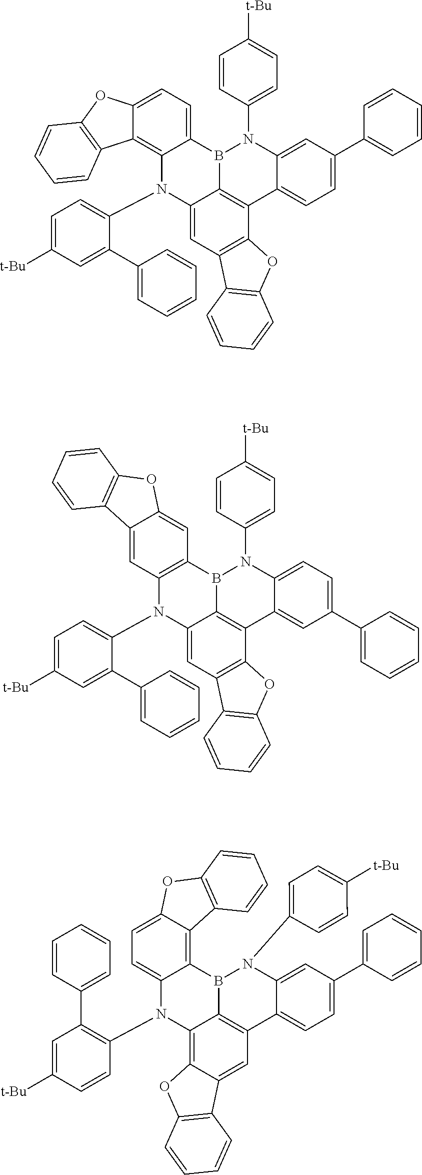 [SMILES: CC(C)(C)c1ccc(N2B3c4ccc5oc6ccccc6c5c4N(c4ccc(C(C)(C)C)cc4-c4ccccc4)c4cc5c(oc6ccccc65)c(c43)-c3ccc(-c4ccccc4)cc32)cc1 ; CC(C)(C)c1ccc(N2B3c4cc5oc6ccccc6c5cc4N(c4ccc(C(C)(C)C)cc4-c4ccccc4)c4cc5c(oc6ccccc65)c(c43)-c3cc(-c4ccccc4)ccc32)cc1 ; CC(C)(C)c1ccc(N2B3c4c(cc5c(oc6ccccc65)c4N(c4ccc(C(C)(C)C)cc4-c4ccccc4)c4ccc5oc6ccccc6c5c43)-c3ccc(-c4ccccc4)cc32)cc1] 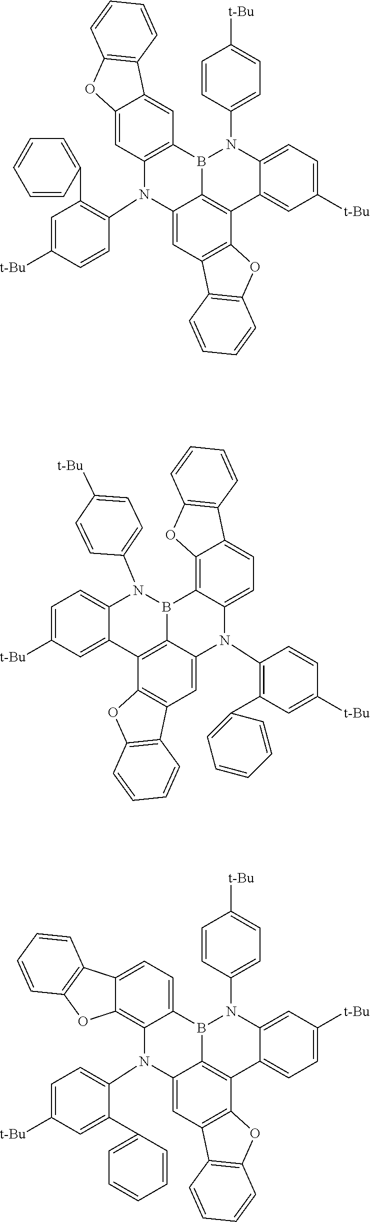 [SMILES: CC(C)(C)c1ccc(N2B3c4cc5c(cc4N(c4ccc(C(C)(C)C)cc4-c4ccccc4)c4cc6c(oc7ccccc76)c(c43)-c3cc(C(C)(C)C)ccc32)oc2ccccc25)cc1 ; CC(C)(C)c1ccc(N2B3c4c(cc5c(oc6ccccc65)c4-c4cc(C(C)(C)C)ccc42)N(c2ccc(C(C)(C)C)cc2-c2ccccc2)c2ccc4c(oc5ccccc54)c23)cc1 ; CC(C)(C)c1ccc(N2B3c4ccc5c(oc6ccccc65)c4N(c4ccc(C(C)(C)C)cc4-c4ccccc4)c4cc5c(oc6ccccc65)c(c43)-c3ccc(C(C)(C)C)cc32)cc1] 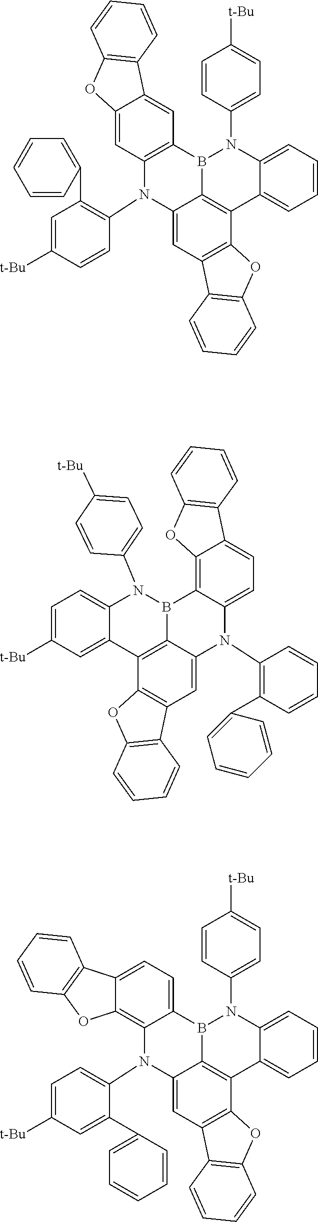 [SMILES: CC(C)(C)c1ccc(N2B3c4cc5c(cc4N(c4ccc(C(C)(C)C)cc4-c4ccccc4)c4cc6c(oc7ccccc76)c(c43)-c3ccccc32)oc2ccccc25)cc1 ; CC(C)(C)c1ccc(N2B3c4c(cc5c(oc6ccccc65)c4-c4cc(C(C)(C)C)ccc42)N(c2ccccc2-c2ccccc2)c2ccc4c(oc5ccccc54)c23)cc1 ; CC(C)(C)c1ccc(N2B3c4ccc5c(oc6ccccc65)c4N(c4ccc(C(C)(C)C)cc4-c4ccccc4)c4cc5c(oc6ccccc65)c(c43)-c3ccccc32)cc1] 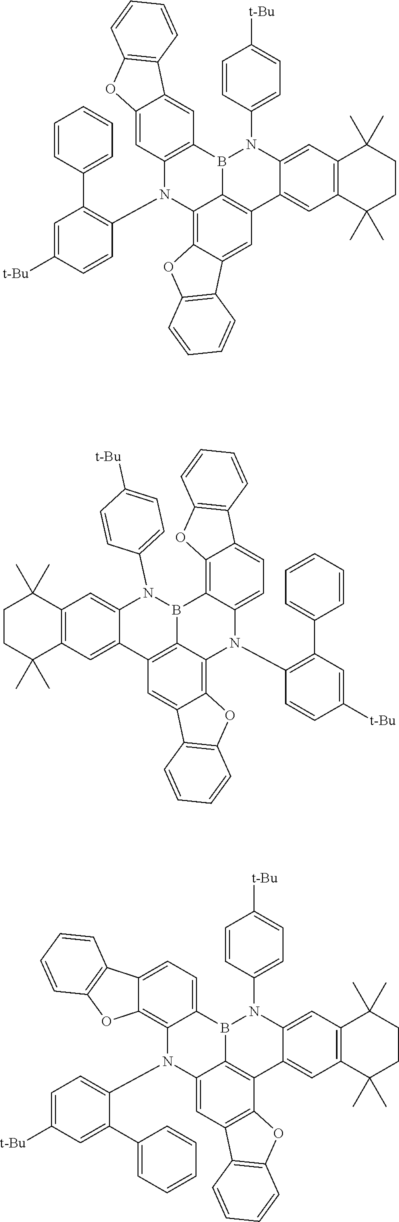 [SMILES: CC(C)(C)c1ccc(N2B3c4cc5c(cc4N(c4ccc(C(C)(C)C)cc4-c4ccccc4)c4c3c(cc3c4oc4ccccc43)-c3cc4c(cc32)C(C)(C)CCC4(C)C)oc2ccccc25)cc1 ; CC(C)(C)c1ccc(N2B3c4c(cc5c(oc6ccccc65)c4N(c4ccc(C(C)(C)C)cc4-c4ccccc4)c4ccc5c(oc6ccccc65)c43)-c3cc4c(cc32)C(C)(C)CCC4(C)C)cc1 ; CC(C)(C)c1ccc(N2B3c4ccc5c(oc6ccccc65)c4N(c4ccc(C(C)(C)C)cc4-c4ccccc4)c4cc5c(oc6ccccc65)c(c43)-c3cc4c(cc32)C(C)(C)CCC4(C)C)cc1] 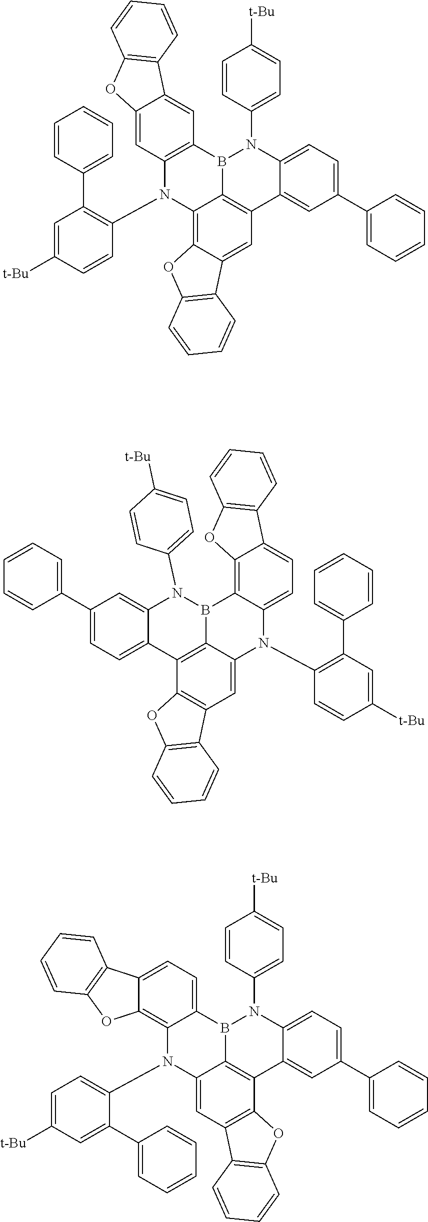 [SMILES: CC(C)(C)c1ccc(N2B3c4cc5c(cc4N(c4ccc(C(C)(C)C)cc4-c4ccccc4)c4c3c(cc3c4oc4ccccc43)-c3cc(-c4ccccc4)ccc32)oc2ccccc25)cc1 ; CC(C)(C)c1ccc(N2B3c4c(cc5c(oc6ccccc65)c4-c4ccc(-c5ccccc5)cc42)N(c2ccc(C(C)(C)C)cc2-c2ccccc2)c2ccc4c(oc5ccccc54)c23)cc1 ; CC(C)(C)c1ccc(N2B3c4ccc5c(oc6ccccc65)c4N(c4ccc(C(C)(C)C)cc4-c4ccccc4)c4cc5c(oc6ccccc65)c(c43)-c3cc(-c4ccccc4)ccc32)cc1] 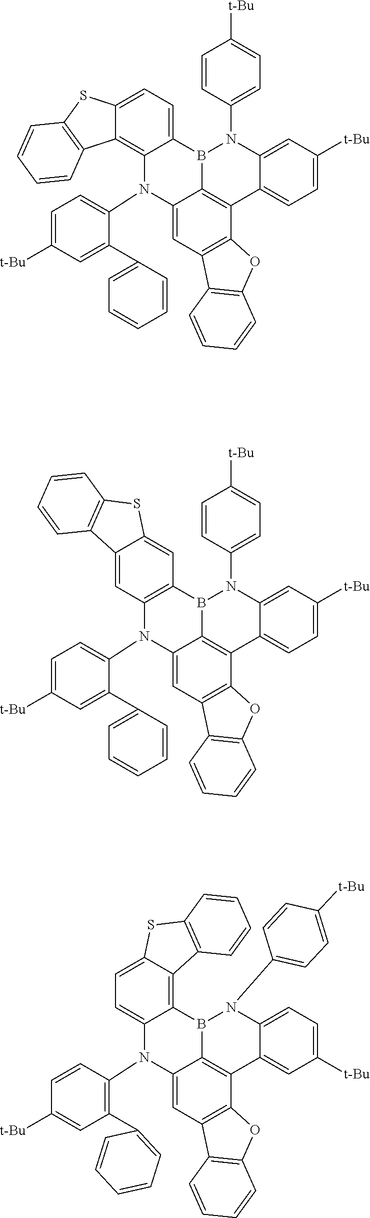 [SMILES: CC(C)(C)c1ccc(N2B3c4ccc5sc6ccccc6c5c4N(c4ccc(C(C)(C)C)cc4-c4ccccc4)c4cc5c(oc6ccccc65)c(c43)-c3ccc(C(C)(C)C)cc32)cc1 ; CC(C)(C)c1ccc(N2B3c4cc5sc6ccccc6c5cc4N(c4ccc(C(C)(C)C)cc4-c4ccccc4)c4cc5c(oc6ccccc65)c(c43)-c3ccc(C(C)(C)C)cc32)cc1 ; CC(C)(C)c1ccc(N2B3c4c(cc5c(oc6ccccc65)c4-c4cc(C(C)(C)C)ccc42)N(c2ccc(C(C)(C)C)cc2-c2ccccc2)c2ccc4sc5ccccc5c4c23)cc1] 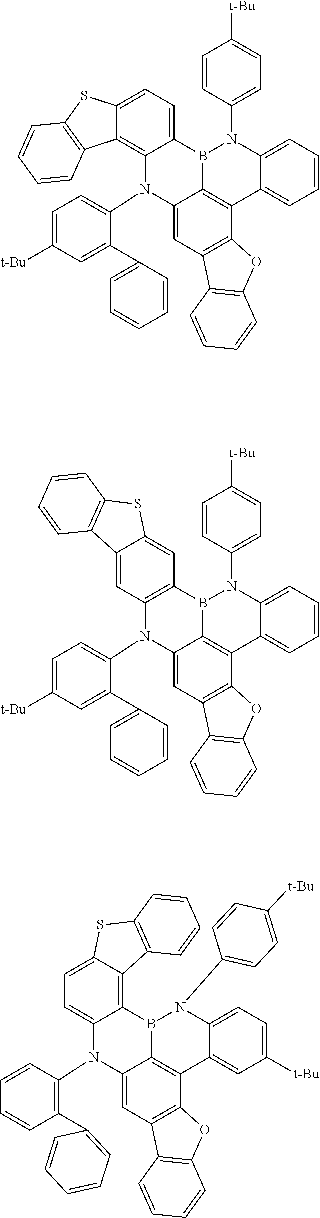 [SMILES: CC(C)(C)c1ccc(N2B3c4ccc5sc6ccccc6c5c4N(c4ccc(C(C)(C)C)cc4-c4ccccc4)c4cc5c(oc6ccccc65)c(c43)-c3ccccc32)cc1 ; CC(C)(C)c1ccc(N2B3c4cc5sc6ccccc6c5cc4N(c4ccc(C(C)(C)C)cc4-c4ccccc4)c4cc5c(oc6ccccc65)c(c43)-c3ccccc32)cc1 ; CC(C)(C)c1ccc(N2B3c4c(cc5c(oc6ccccc65)c4-c4cc(C(C)(C)C)ccc42)N(c2ccccc2-c2ccccc2)c2ccc4sc5ccccc5c4c23)cc1] 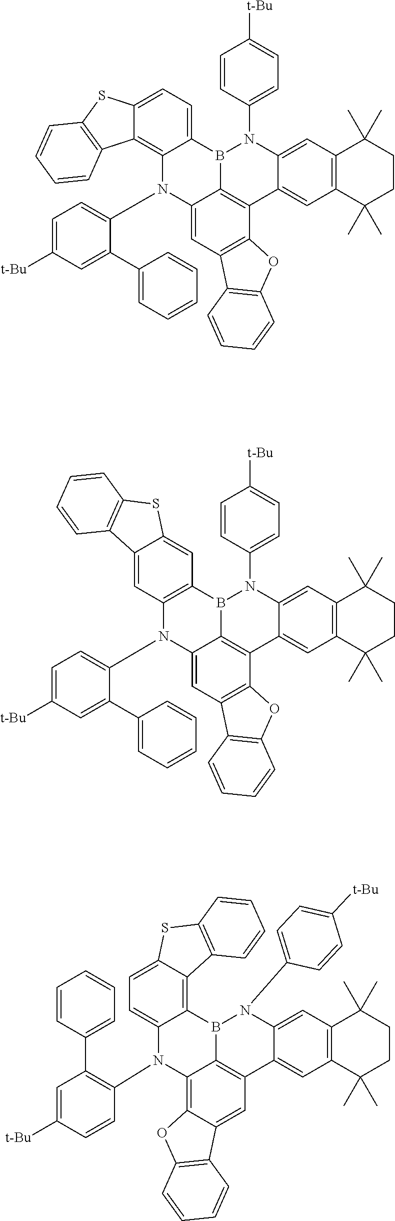 [SMILES: CC(C)(C)c1ccc(N2B3c4ccc5sc6ccccc6c5c4N(c4ccc(C(C)(C)C)cc4-c4ccccc4)c4cc5c(oc6ccccc65)c(c43)-c3cc4c(cc32)C(C)(C)CCC4(C)C)cc1 ; CC(C)(C)c1ccc(N2B3c4cc5sc6ccccc6c5cc4N(c4ccc(C(C)(C)C)cc4-c4ccccc4)c4cc5c(oc6ccccc65)c(c43)-c3cc4c(cc32)C(C)(C)CCC4(C)C)cc1 ; CC(C)(C)c1ccc(N2B3c4c(cc5c(oc6ccccc65)c4N(c4ccc(C(C)(C)C)cc4-c4ccccc4)c4ccc5sc6ccccc6c5c43)-c3cc4c(cc32)C(C)(C)CCC4(C)C)cc1] 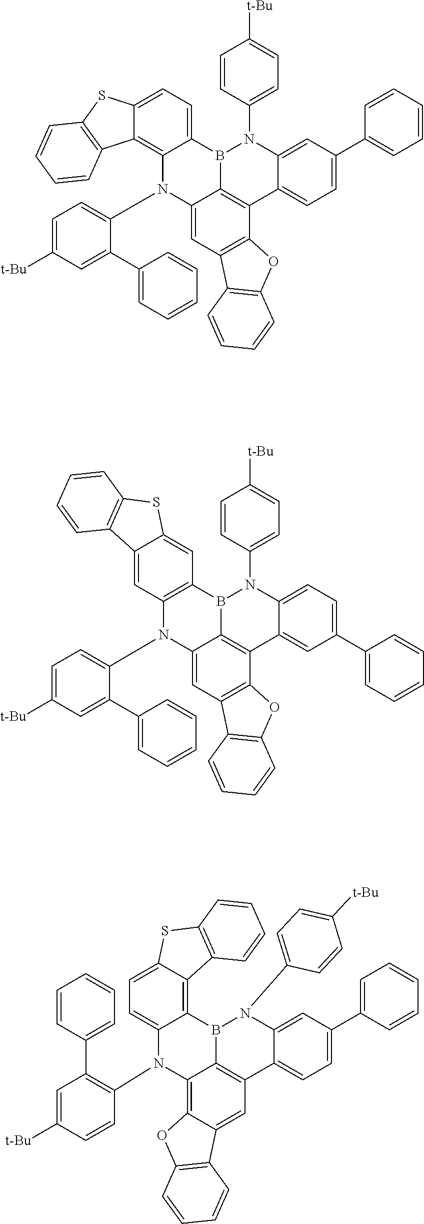 [SMILES: CC(C)(C)c1ccc(N2B3c4ccc5sc6ccccc6c5c4N(c4ccc(C(C)(C)C)cc4-c4ccccc4)c4cc5c(oc6ccccc65)c(c43)-c3ccc(-c4ccccc4)cc32)cc1 ; CC(C)(C)c1ccc(N2B3c4cc5sc6ccccc6c5cc4N(c4ccc(C(C)(C)C)cc4-c4ccccc4)c4cc5c(oc6ccccc65)c(c43)-c3cc(-c4ccccc4)ccc32)cc1 ; CC(C)(C)c1ccc(N2B3c4c(cc5c(oc6ccccc65)c4N(c4ccc(C(C)(C)C)cc4-c4ccccc4)c4ccc5sc6ccccc6c5c43)-c3ccc(-c4ccccc4)cc32)cc1] 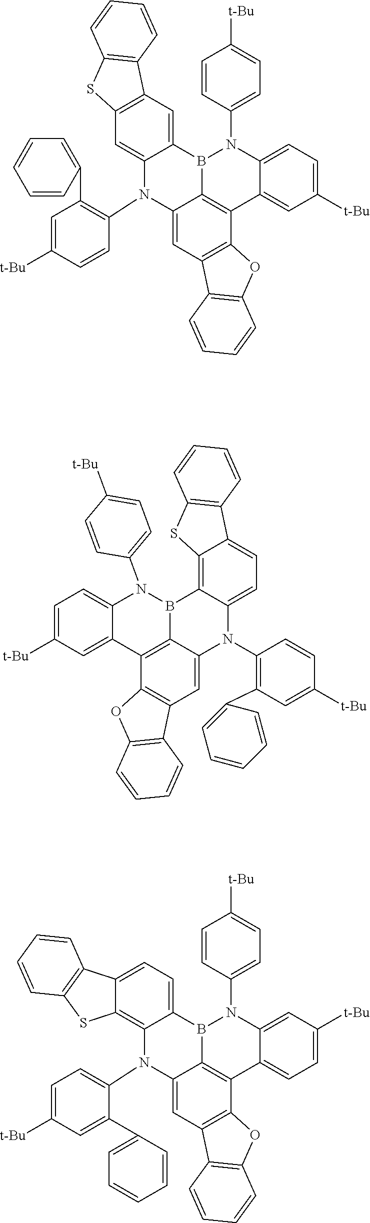 [SMILES: CC(C)(C)c1ccc(N2B3c4cc5c(cc4N(c4ccc(C(C)(C)C)cc4-c4ccccc4)c4cc6c(oc7ccccc76)c(c43)-c3cc(C(C)(C)C)ccc32)sc2ccccc25)cc1 ; CC(C)(C)c1ccc(N2B3c4c(cc5c(oc6ccccc65)c4-c4cc(C(C)(C)C)ccc42)N(c2ccc(C(C)(C)C)cc2-c2ccccc2)c2ccc4c(sc5ccccc54)c23)cc1 ; CC(C)(C)c1ccc(N2B3c4ccc5c(sc6ccccc65)c4N(c4ccc(C(C)(C)C)cc4-c4ccccc4)c4cc5c(oc6ccccc65)c(c43)-c3ccc(C(C)(C)C)cc32)cc1] 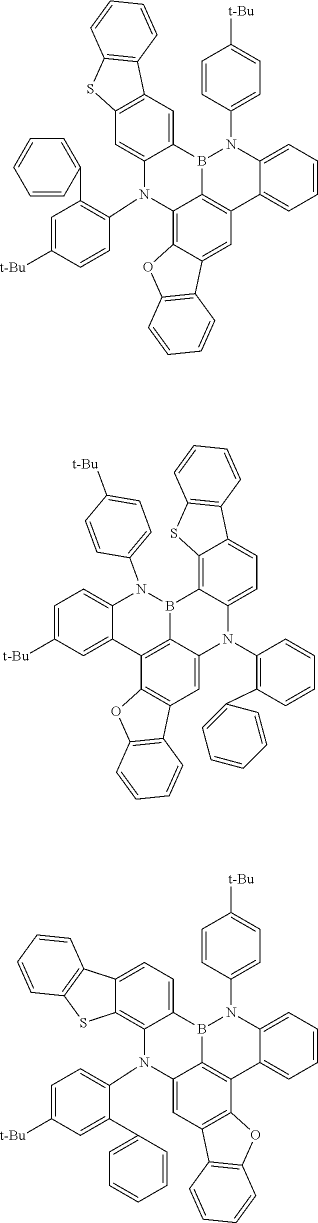 [SMILES: CC(C)(C)c1ccc(N2B3c4cc5c(cc4N(c4ccc(C(C)(C)C)cc4-c4ccccc4)c4c3c(cc3c4oc4ccccc43)-c3ccccc32)sc2ccccc25)cc1 ; CC(C)(C)c1ccc(N2B3c4c(cc5c(oc6ccccc65)c4-c4cc(C(C)(C)C)ccc42)N(c2ccccc2-c2ccccc2)c2ccc4c(sc5ccccc54)c23)cc1 ; CC(C)(C)c1ccc(N2B3c4ccc5c(sc6ccccc65)c4N(c4ccc(C(C)(C)C)cc4-c4ccccc4)c4cc5c(oc6ccccc65)c(c43)-c3ccccc32)cc1] 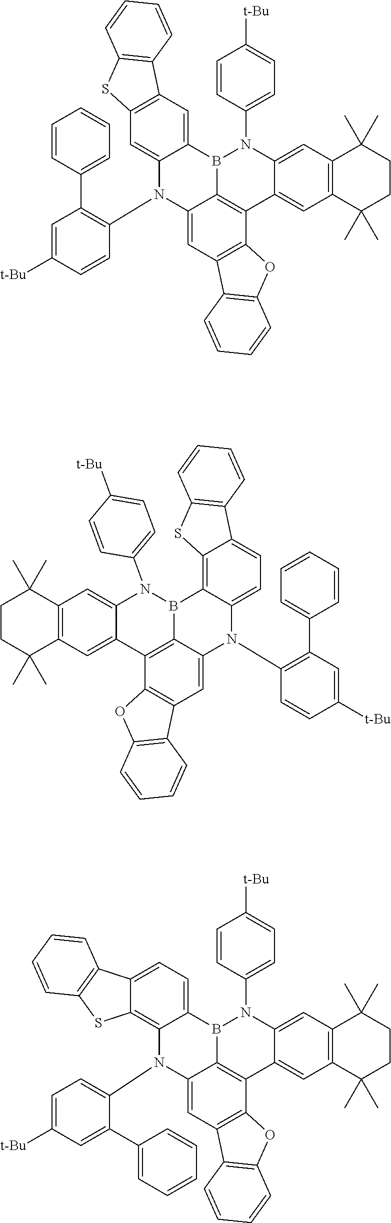 [SMILES: CC(C)(C)c1ccc(N2B3c4cc5c(cc4N(c4ccc(C(C)(C)C)cc4-c4ccccc4)c4cc6c(oc7ccccc76)c(c43)-c3cc4c(cc32)C(C)(C)CCC4(C)C)sc2ccccc25)cc1 ; CC(C)(C)c1ccc(N2B3c4c(cc5c(oc6ccccc65)c4-c4cc5c(cc42)C(C)(C)CCC5(C)C)N(c2ccc(C(C)(C)C)cc2-c2ccccc2)c2ccc4c(sc5ccccc54)c23)cc1 ; CC(C)(C)c1ccc(N2B3c4ccc5c(sc6ccccc65)c4N(c4ccc(C(C)(C)C)cc4-c4ccccc4)c4cc5c(oc6ccccc65)c(c43)-c3cc4c(cc32)C(C)(C)CCC4(C)C)cc1] 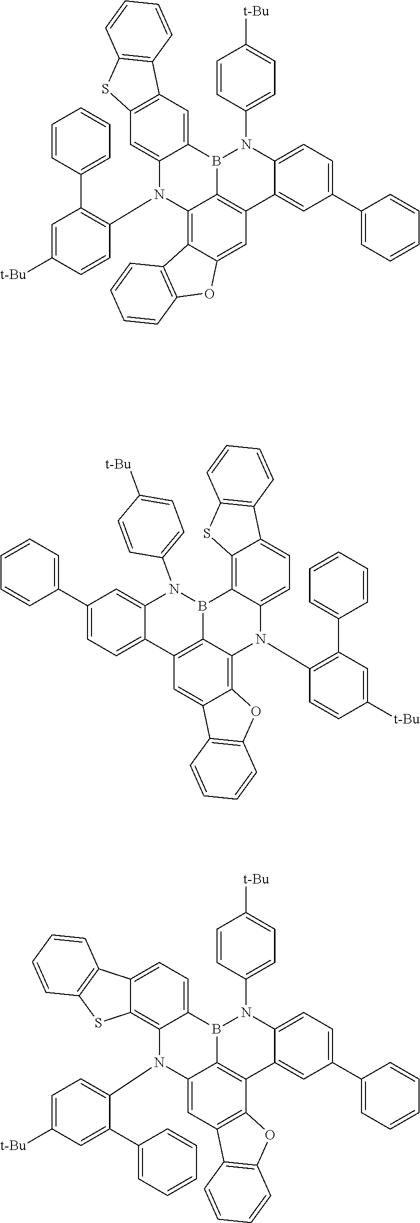 [SMILES: CC(C)(C)c1ccc(N2B3c4cc5c(cc4N(c4ccc(C(C)(C)C)cc4-c4ccccc4)c4c3c(cc3oc6ccccc6c43)-c3cc(-c4ccccc4)ccc32)sc2ccccc25)cc1 ; CC(C)(C)c1ccc(N2B3c4c(cc5c(oc6ccccc65)c4N(c4ccc(C(C)(C)C)cc4-c4ccccc4)c4ccc5c(sc6ccccc65)c43)-c3ccc(-c4ccccc4)cc32)cc1 ; CC(C)(C)c1ccc(N2B3c4ccc5c(sc6ccccc65)c4N(c4ccc(C(C)(C)C)cc4-c4ccccc4)c4cc5c(oc6ccccc65)c(c43)-c3cc(-c4ccccc4)ccc32)cc1] 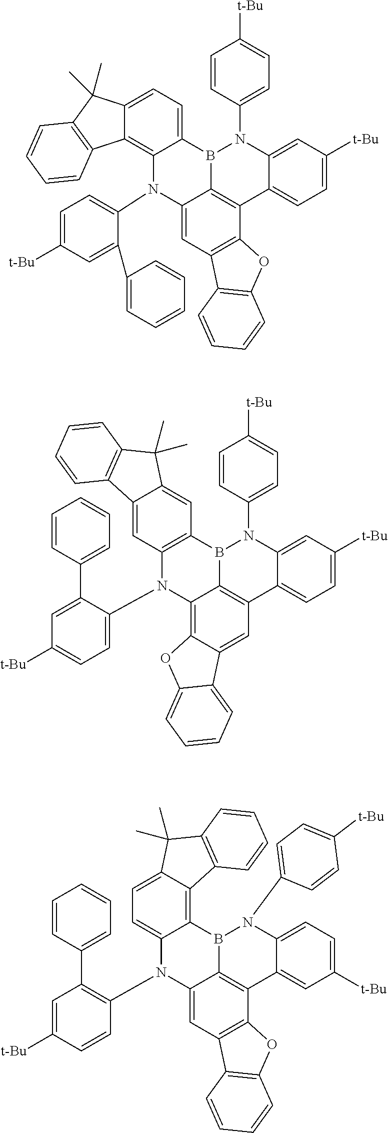 [SMILES: CC(C)(C)c1ccc(N2B3c4ccc5c(c4N(c4ccc(C(C)(C)C)cc4-c4ccccc4)c4cc6c(oc7ccccc76)c(c43)-c3ccc(C(C)(C)C)cc32)-c2ccccc2C5(C)C)cc1 ; CC(C)(C)c1ccc(N2B3c4cc5c(cc4N(c4ccc(C(C)(C)C)cc4-c4ccccc4)c4c3c(cc3c4oc4ccccc43)-c3ccc(C(C)(C)C)cc32)-c2ccccc2C5(C)C)cc1 ; CC(C)(C)c1ccc(N2B3c4c(ccc5c4-c4ccccc4C5(C)C)N(c4ccc(C(C)(C)C)cc4-c4ccccc4)c4cc5c(oc6ccccc65)c(c43)-c3cc(C(C)(C)C)ccc32)cc1] 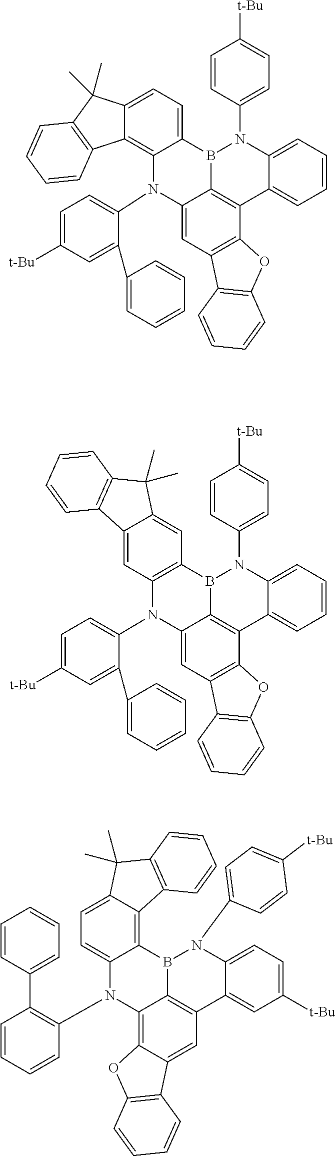 [SMILES: CC(C)(C)c1ccc(N2B3c4ccc5c(c4N(c4ccc(C(C)(C)C)cc4-c4ccccc4)c4cc6c(oc7ccccc76)c(c43)-c3ccccc32)-c2ccccc2C5(C)C)cc1 ; CC(C)(C)c1ccc(N2B3c4cc5c(cc4N(c4ccc(C(C)(C)C)cc4-c4ccccc4)c4cc6c(oc7ccccc76)c(c43)-c3ccccc32)-c2ccccc2C5(C)C)cc1 ; CC(C)(C)c1ccc(N2B3c4c(ccc5c4-c4ccccc4C5(C)C)N(c4ccccc4-c4ccccc4)c4c3c(cc3c4oc4ccccc43)-c3cc(C(C)(C)C)ccc32)cc1] 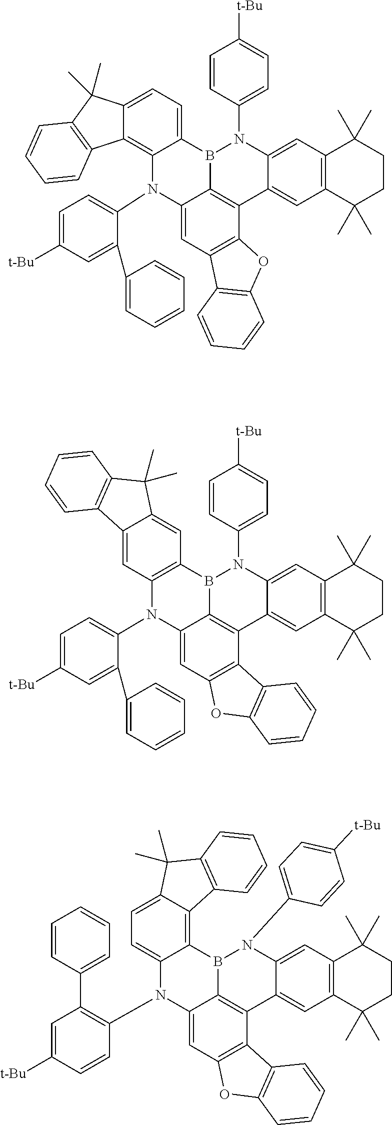 [SMILES: CC(C)(C)c1ccc(N2B3c4ccc5c(c4N(c4ccc(C(C)(C)C)cc4-c4ccccc4)c4cc6c(oc7ccccc76)c(c43)-c3cc4c(cc32)C(C)(C)CCC4(C)C)-c2ccccc2C5(C)C)cc1 ; CC(C)(C)c1ccc(N2B3c4cc5c(cc4N(c4ccc(C(C)(C)C)cc4-c4ccccc4)c4cc6oc7ccccc7c6c(c43)-c3cc4c(cc32)C(C)(C)CCC4(C)C)-c2ccccc2C5(C)C)cc1 ; CC(C)(C)c1ccc(N2B3c4c(ccc5c4-c4ccccc4C5(C)C)N(c4ccc(C(C)(C)C)cc4-c4ccccc4)c4cc5oc6ccccc6c5c(c43)-c3cc4c(cc32)C(C)(C)CCC4(C)C)cc1] 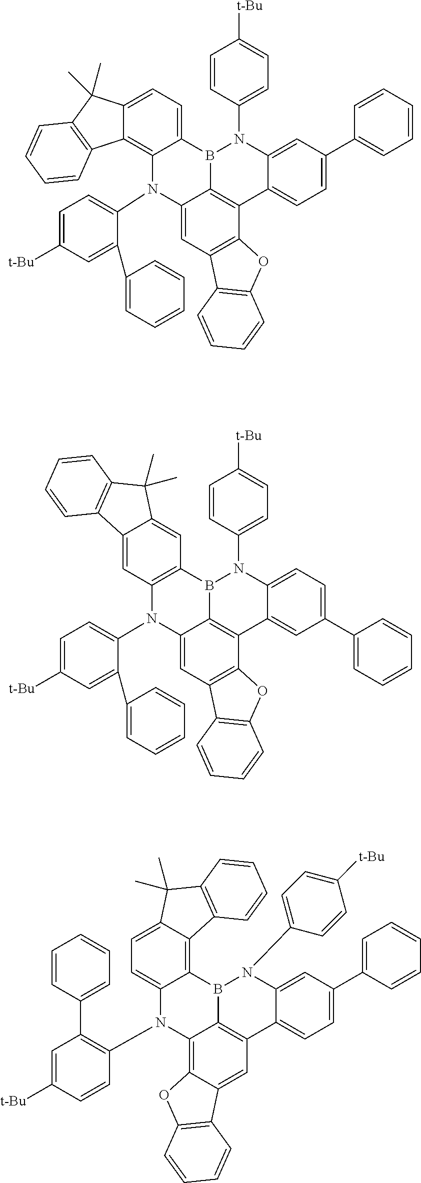 [SMILES: CC(C)(C)c1ccc(N2B3c4ccc5c(c4N(c4ccc(C(C)(C)C)cc4-c4ccccc4)c4cc6c(oc7ccccc76)c(c43)-c3ccc(-c4ccccc4)cc32)-c2ccccc2C5(C)C)cc1 ; CC(C)(C)c1ccc(N2B3c4cc5c(cc4N(c4ccc(C(C)(C)C)cc4-c4ccccc4)c4cc6c(oc7ccccc76)c(c43)-c3cc(-c4ccccc4)ccc32)-c2ccccc2C5(C)C)cc1 ; CC(C)(C)c1ccc(N2B3c4c(ccc5c4-c4ccccc4C5(C)C)N(c4ccc(C(C)(C)C)cc4-c4ccccc4)c4c3c(cc3c4oc4ccccc43)-c3ccc(-c4ccccc4)cc32)cc1] 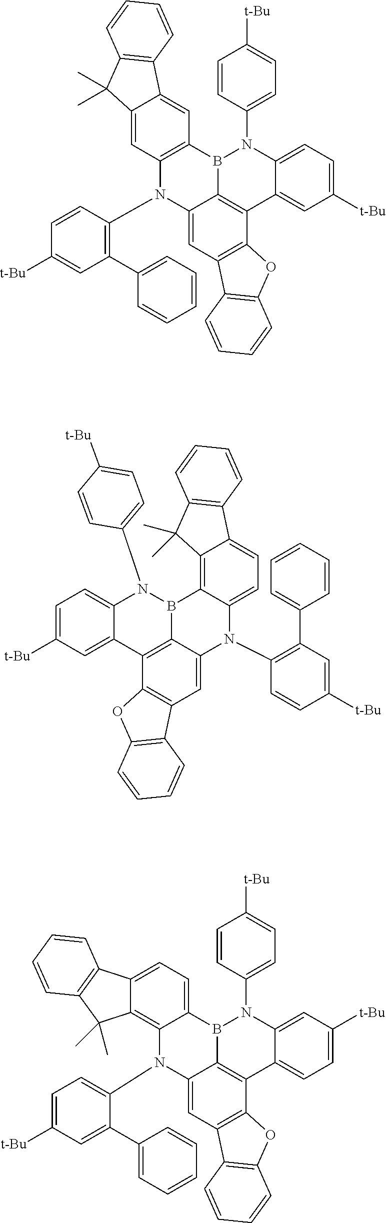 [SMILES: CC(C)(C)c1ccc(N2B3c4cc5c(cc4N(c4ccc(C(C)(C)C)cc4-c4ccccc4)c4cc6c(oc7ccccc76)c(c43)-c3cc(C(C)(C)C)ccc32)C(C)(C)c2ccccc2-5)cc1 ; CC(C)(C)c1ccc(N2B3c4c(ccc5c4C(C)(C)c4ccccc4-5)N(c4ccc(C(C)(C)C)cc4-c4ccccc4)c4cc5c(oc6ccccc65)c(c43)-c3cc(C(C)(C)C)ccc32)cc1 ; CC(C)(C)c1ccc(N2B3c4ccc5c(c4N(c4ccc(C(C)(C)C)cc4-c4ccccc4)c4cc6c(oc7ccccc76)c(c43)-c3ccc(C(C)(C)C)cc32)C(C)(C)c2ccccc2-5)cc1] 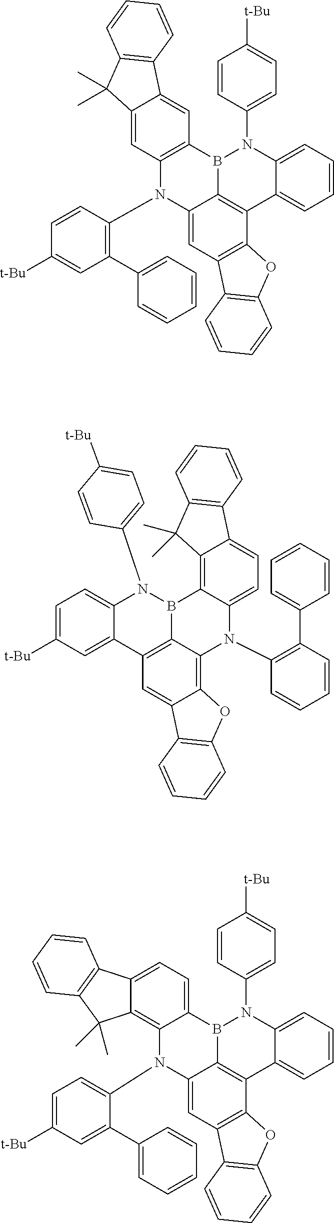 [SMILES: CC(C)(C)c1ccc(N2B3c4cc5c(cc4N(c4ccc(C(C)(C)C)cc4-c4ccccc4)c4cc6c(oc7ccccc76)c(c43)-c3ccccc32)C(C)(C)c2ccccc2-5)cc1 ; CC(C)(C)c1ccc(N2B3c4c(ccc5c4C(C)(C)c4ccccc4-5)N(c4ccccc4-c4ccccc4)c4c3c(cc3c4oc4ccccc43)-c3cc(C(C)(C)C)ccc32)cc1 ; CC(C)(C)c1ccc(N2B3c4ccc5c(c4N(c4ccc(C(C)(C)C)cc4-c4ccccc4)c4cc6c(oc7ccccc76)c(c43)-c3ccccc32)C(C)(C)c2ccccc2-5)cc1] 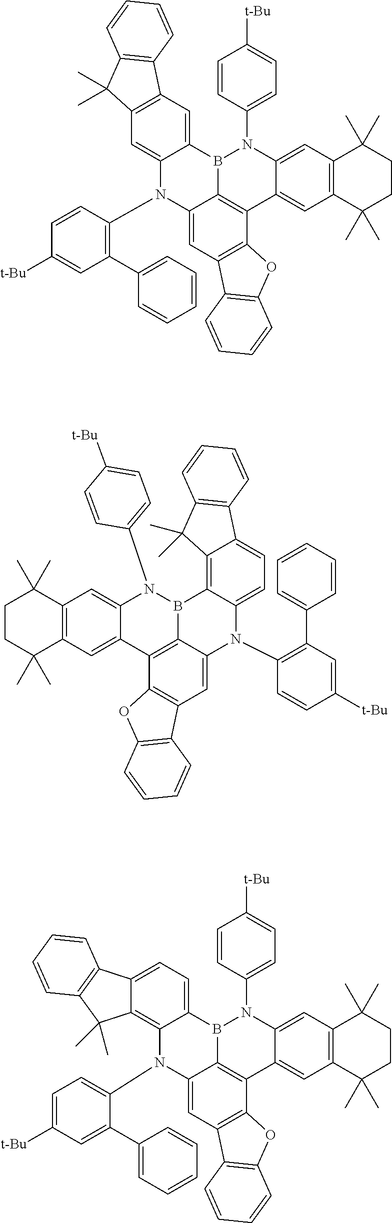 [SMILES: CC(C)(C)c1ccc(N2B3c4cc5c(cc4N(c4ccc(C(C)(C)C)cc4-c4ccccc4)c4cc6c(oc7ccccc76)c(c43)-c3cc4c(cc32)C(C)(C)CCC4(C)C)C(C)(C)c2ccccc2-5)cc1 ; CC(C)(C)c1ccc(N2B3c4c(ccc5c4C(C)(C)c4ccccc4-5)N(c4ccc(C(C)(C)C)cc4-c4ccccc4)c4cc5c(oc6ccccc65)c(c43)-c3cc4c(cc32)C(C)(C)CCC4(C)C)cc1 ; CC(C)(C)c1ccc(N2B3c4ccc5c(c4N(c4ccc(C(C)(C)C)cc4-c4ccccc4)c4cc6c(oc7ccccc76)c(c43)-c3cc4c(cc32)C(C)(C)CCC4(C)C)C(C)(C)c2ccccc2-5)cc1] 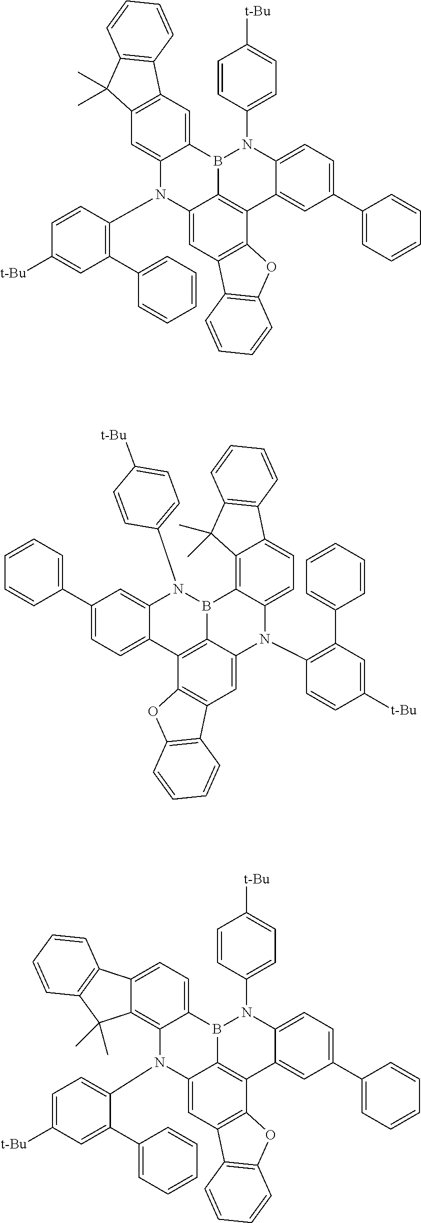 [SMILES: CC(C)(C)c1ccc(N2B3c4cc5c(cc4N(c4ccc(C(C)(C)C)cc4-c4ccccc4)c4cc6c(oc7ccccc76)c(c43)-c3cc(-c4ccccc4)ccc32)C(C)(C)c2ccccc2-5)cc1 ; CC(C)(C)c1ccc(N2B3c4c(ccc5c4C(C)(C)c4ccccc4-5)N(c4ccc(C(C)(C)C)cc4-c4ccccc4)c4cc5c(oc6ccccc65)c(c43)-c3ccc(-c4ccccc4)cc32)cc1 ; CC(C)(C)c1ccc(N2B3c4ccc5c(c4N(c4ccc(C(C)(C)C)cc4-c4ccccc4)c4cc6c(oc7ccccc76)c(c43)-c3cc(-c4ccccc4)ccc32)C(C)(C)c2ccccc2-5)cc1] 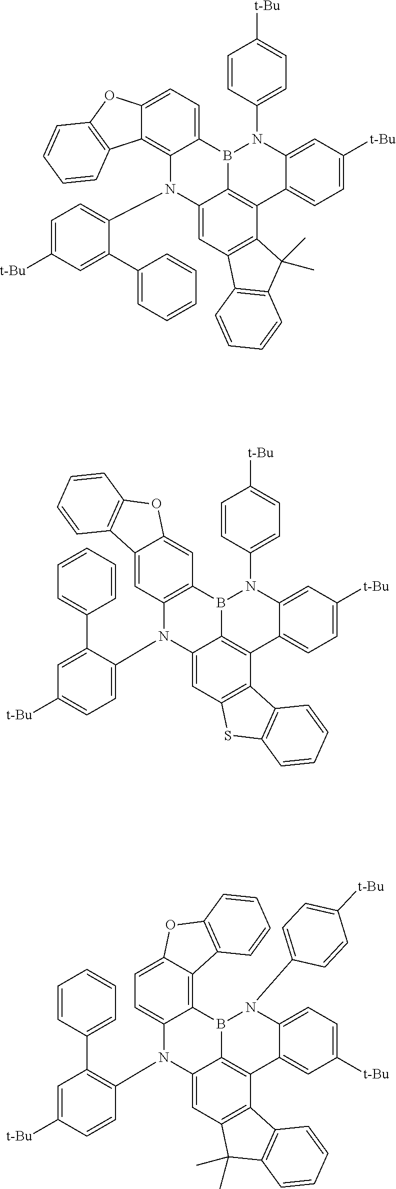 [SMILES: CC(C)(C)c1ccc(N2B3c4ccc5oc6ccccc6c5c4N(c4ccc(C(C)(C)C)cc4-c4ccccc4)c4cc5c(c(c43)-c3ccc(C(C)(C)C)cc32)C(C)(C)c2ccccc2-5)cc1 ; CC(C)(C)c1ccc(N2B3c4cc5oc6ccccc6c5cc4N(c4ccc(C(C)(C)C)cc4-c4ccccc4)c4cc5sc6ccccc6c5c(c43)-c3ccc(C(C)(C)C)cc32)cc1 ; CC(C)(C)c1ccc(N2B3c4c(cc5c(c4-c4cc(C(C)(C)C)ccc42)-c2ccccc2C5(C)C)N(c2ccc(C(C)(C)C)cc2-c2ccccc2)c2ccc4oc5ccccc5c4c23)cc1] 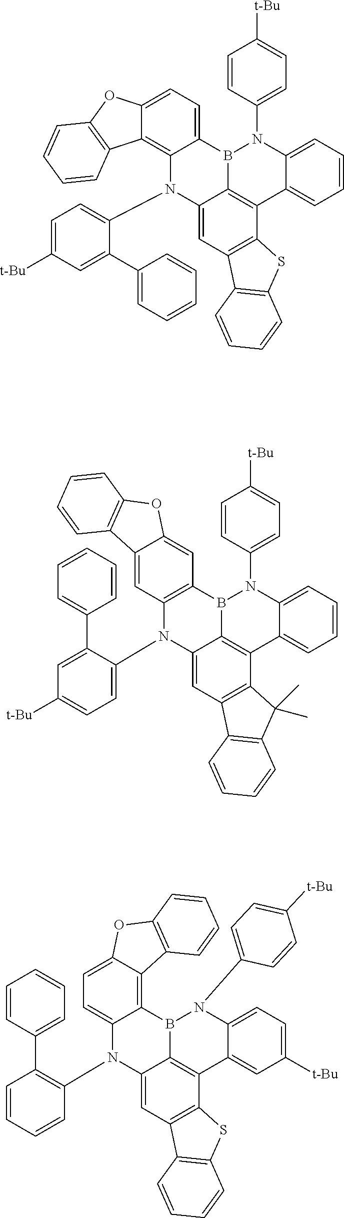 [SMILES: CC(C)(C)c1ccc(N2B3c4ccc5oc6ccccc6c5c4N(c4ccc(C(C)(C)C)cc4-c4ccccc4)c4cc5c(sc6ccccc65)c(c43)-c3ccccc32)cc1 ; CC(C)(C)c1ccc(N2B3c4cc5oc6ccccc6c5cc4N(c4ccc(C(C)(C)C)cc4-c4ccccc4)c4cc5c(c(c43)-c3ccccc32)C(C)(C)c2ccccc2-5)cc1 ; CC(C)(C)c1ccc(N2B3c4c(cc5c(sc6ccccc65)c4-c4cc(C(C)(C)C)ccc42)N(c2ccccc2-c2ccccc2)c2ccc4oc5ccccc5c4c23)cc1] 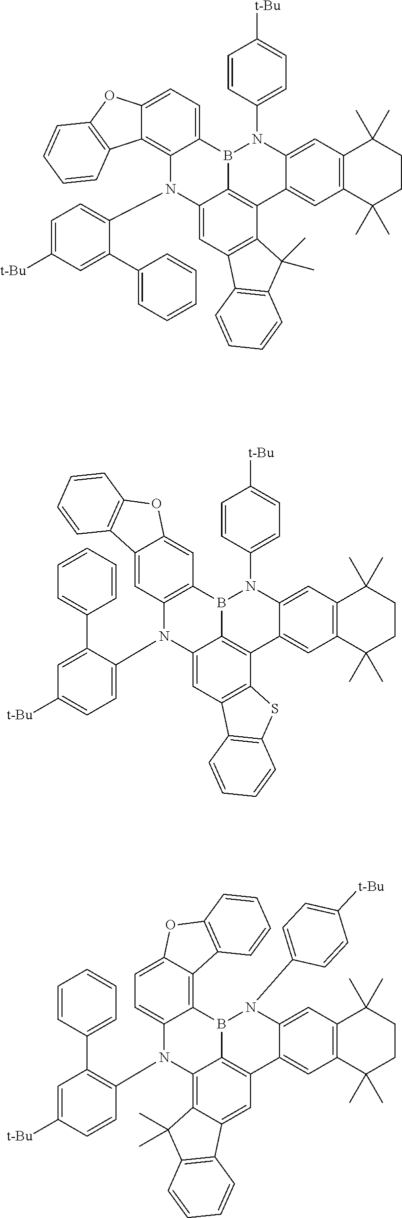 [SMILES: CC(C)(C)c1ccc(N2B3c4ccc5oc6ccccc6c5c4N(c4ccc(C(C)(C)C)cc4-c4ccccc4)c4cc5c(c(c43)-c3cc4c(cc32)C(C)(C)CCC4(C)C)C(C)(C)c2ccccc2-5)cc1 ; CC(C)(C)c1ccc(N2B3c4cc5oc6ccccc6c5cc4N(c4ccc(C(C)(C)C)cc4-c4ccccc4)c4cc5c(sc6ccccc65)c(c43)-c3cc4c(cc32)C(C)(C)CCC4(C)C)cc1 ; CC(C)(C)c1ccc(N2B3c4c(cc5c(c4N(c4ccc(C(C)(C)C)cc4-c4ccccc4)c4ccc6oc7ccccc7c6c43)C(C)(C)c3ccccc3-5)-c3cc4c(cc32)C(C)(C)CCC4(C)C)cc1] 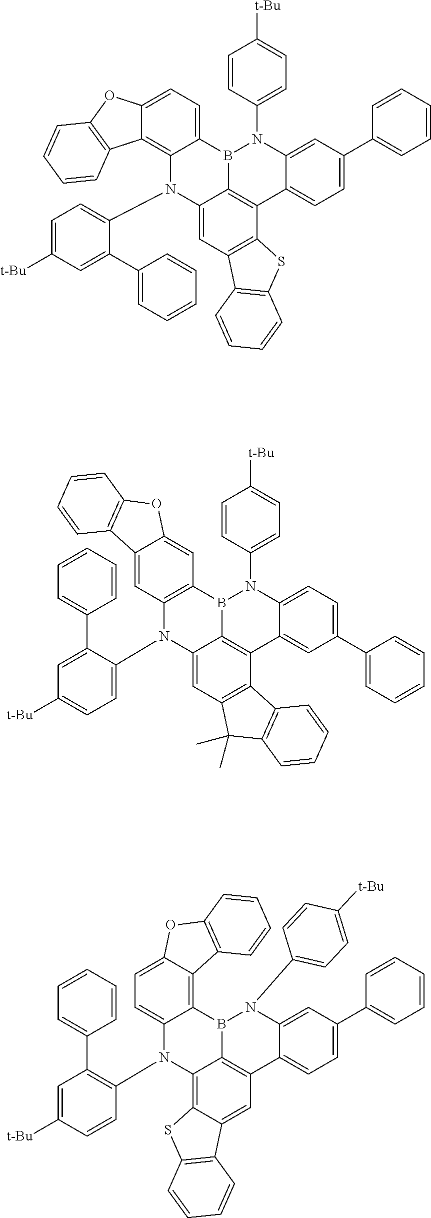 [SMILES: CC(C)(C)c1ccc(N2B3c4ccc5oc6ccccc6c5c4N(c4ccc(C(C)(C)C)cc4-c4ccccc4)c4cc5c(sc6ccccc65)c(c43)-c3ccc(-c4ccccc4)cc32)cc1 ; CC(C)(C)c1ccc(N2B3c4cc5oc6ccccc6c5cc4N(c4ccc(C(C)(C)C)cc4-c4ccccc4)c4cc5c(c(c43)-c3cc(-c4ccccc4)ccc32)-c2ccccc2C5(C)C)cc1 ; CC(C)(C)c1ccc(N2B3c4c(cc5c(sc6ccccc65)c4N(c4ccc(C(C)(C)C)cc4-c4ccccc4)c4ccc5oc6ccccc6c5c43)-c3ccc(-c4ccccc4)cc32)cc1] 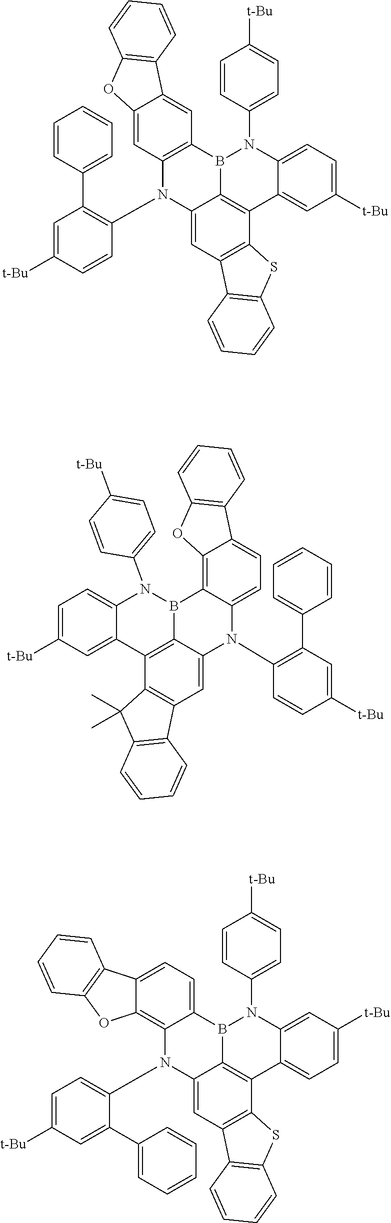 [SMILES: CC(C)(C)c1ccc(N2B3c4cc5c(cc4N(c4ccc(C(C)(C)C)cc4-c4ccccc4)c4cc6c(sc7ccccc76)c(c43)-c3cc(C(C)(C)C)ccc32)oc2ccccc25)cc1 ; CC(C)(C)c1ccc(N2B3c4c(cc5c(c4-c4cc(C(C)(C)C)ccc42)C(C)(C)c2ccccc2-5)N(c2ccc(C(C)(C)C)cc2-c2ccccc2)c2ccc4c(oc5ccccc54)c23)cc1 ; CC(C)(C)c1ccc(N2B3c4ccc5c(oc6ccccc65)c4N(c4ccc(C(C)(C)C)cc4-c4ccccc4)c4cc5c(sc6ccccc65)c(c43)-c3ccc(C(C)(C)C)cc32)cc1] 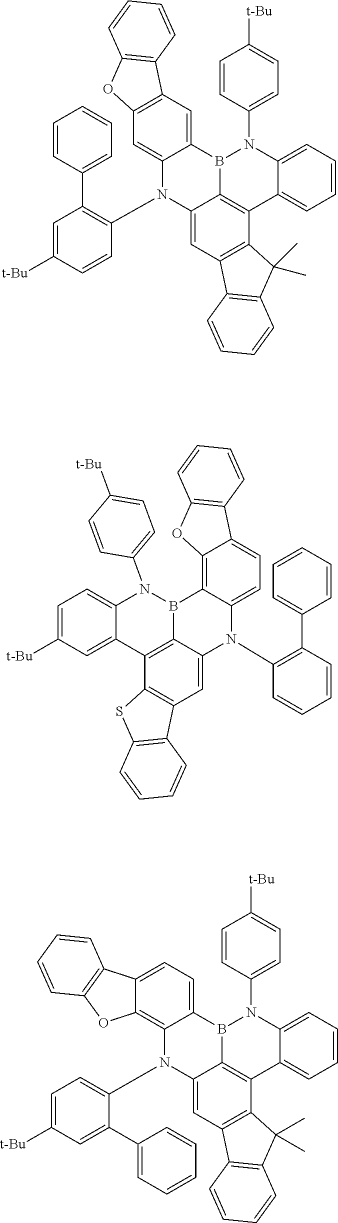 [SMILES: CC(C)(C)c1ccc(N2B3c4cc5c(cc4N(c4ccc(C(C)(C)C)cc4-c4ccccc4)c4cc6c(c(c43)-c3ccccc32)C(C)(C)c2ccccc2-6)oc2ccccc25)cc1 ; CC(C)(C)c1ccc(N2B3c4c(cc5c(sc6ccccc65)c4-c4cc(C(C)(C)C)ccc42)N(c2ccccc2-c2ccccc2)c2ccc4c(oc5ccccc54)c23)cc1 ; CC(C)(C)c1ccc(N2B3c4ccc5c(oc6ccccc65)c4N(c4ccc(C(C)(C)C)cc4-c4ccccc4)c4cc5c(c(c43)-c3ccccc32)C(C)(C)c2ccccc2-5)cc1] 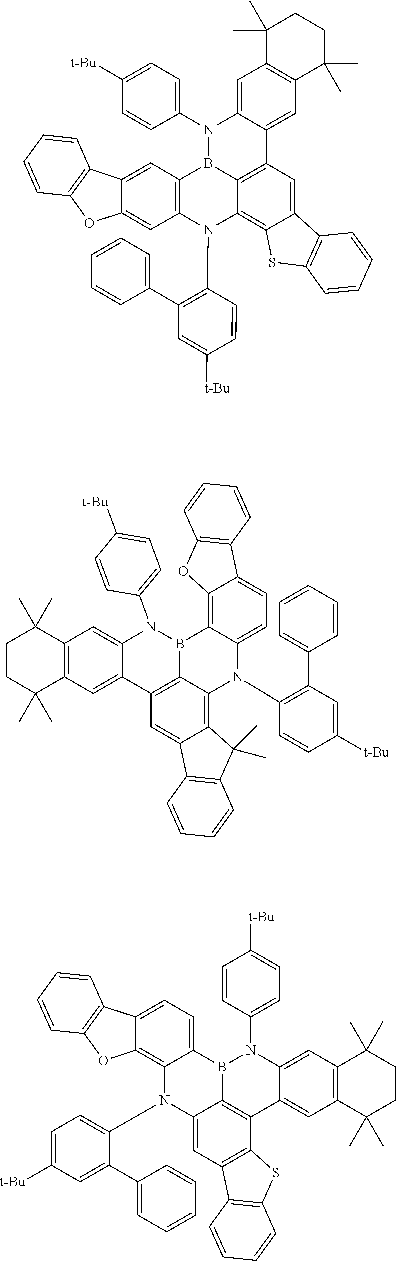 [SMILES: CC(C)(C)c1ccc(N2B3c4cc5c(cc4N(c4ccc(C(C)(C)C)cc4-c4ccccc4)c4c3c(cc3c4sc4ccccc43)-c3cc4c(cc32)C(C)(C)CCC4(C)C)oc2ccccc25)cc1 ; CC(C)(C)c1ccc(N2B3c4c(cc5c(c4N(c4ccc(C(C)(C)C)cc4-c4ccccc4)c4ccc6c(oc7ccccc76)c43)C(C)(C)c3ccccc3-5)-c3cc4c(cc32)C(C)(C)CCC4(C)C)cc1 ; CC(C)(C)c1ccc(N2B3c4ccc5c(oc6ccccc65)c4N(c4ccc(C(C)(C)C)cc4-c4ccccc4)c4cc5c(sc6ccccc65)c(c43)-c3cc4c(cc32)C(C)(C)CCC4(C)C)cc1] 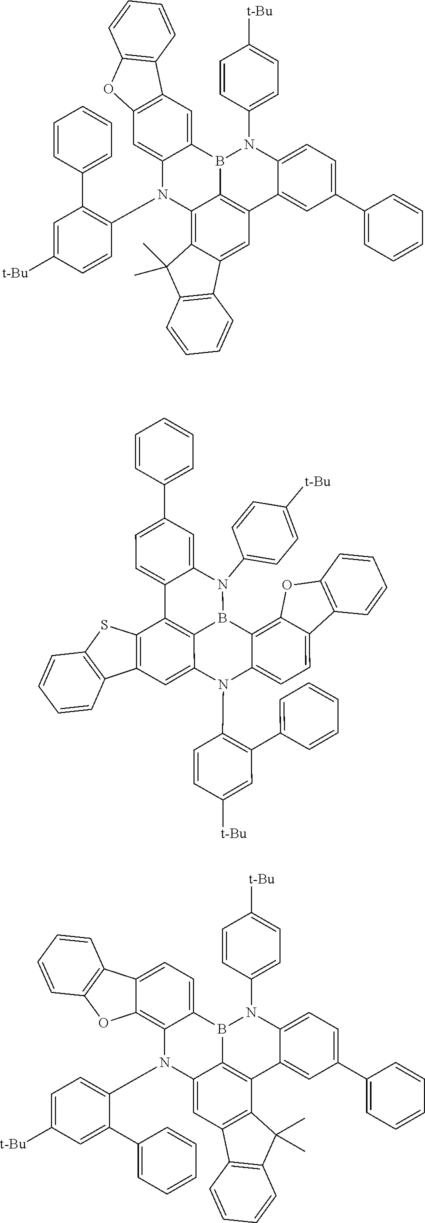 [SMILES: CC(C)(C)c1ccc(N2B3c4cc5c(cc4N(c4ccc(C(C)(C)C)cc4-c4ccccc4)c4c3c(cc3c4C(C)(C)c4ccccc4-3)-c3cc(-c4ccccc4)ccc32)oc2ccccc25)cc1 ; CC(C)(C)c1ccc(N2B3c4c(cc5c(sc6ccccc65)c4-c4ccc(-c5ccccc5)cc42)N(c2ccc(C(C)(C)C)cc2-c2ccccc2)c2ccc4c(oc5ccccc54)c23)cc1 ; CC(C)(C)c1ccc(N2B3c4ccc5c(oc6ccccc65)c4N(c4ccc(C(C)(C)C)cc4-c4ccccc4)c4cc5c(c(c43)-c3cc(-c4ccccc4)ccc32)C(C)(C)c2ccccc2-5)cc1] 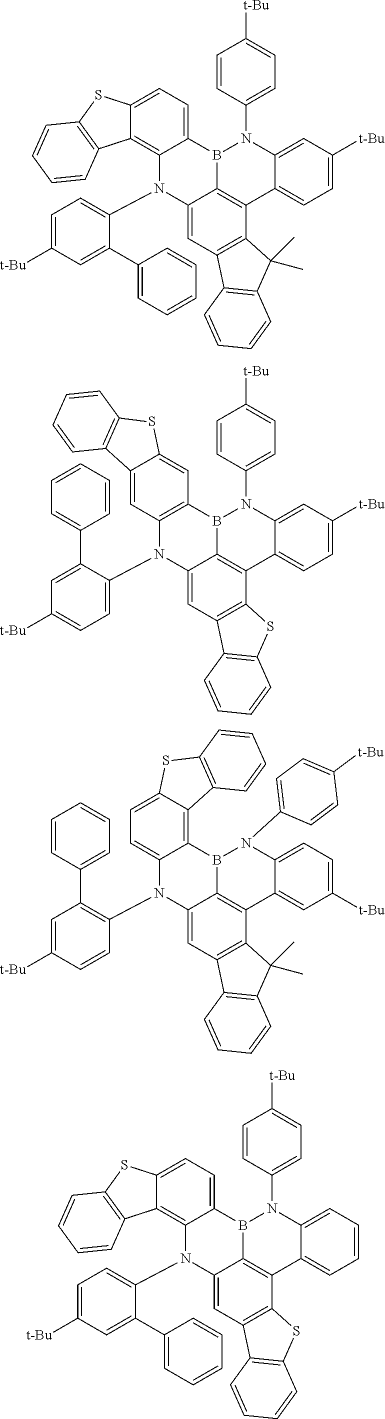 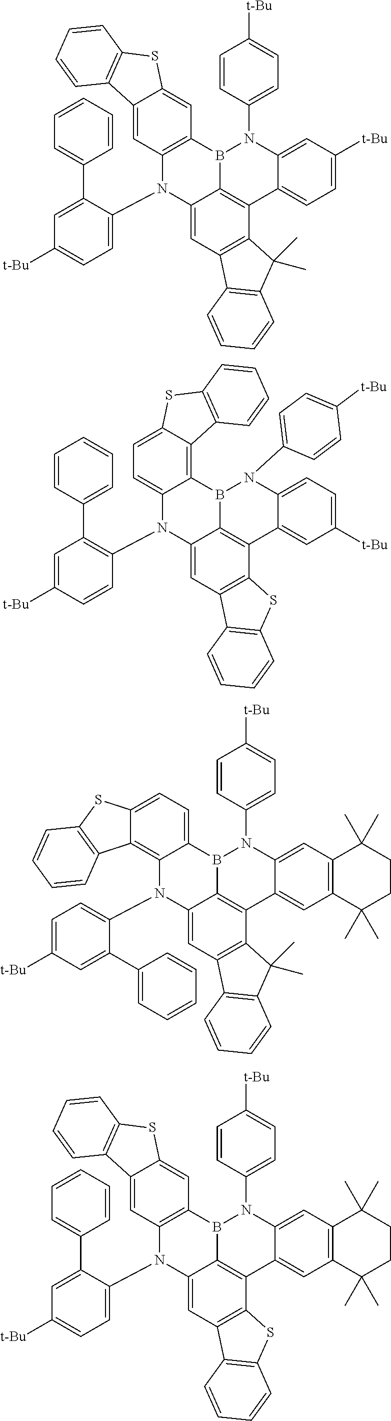 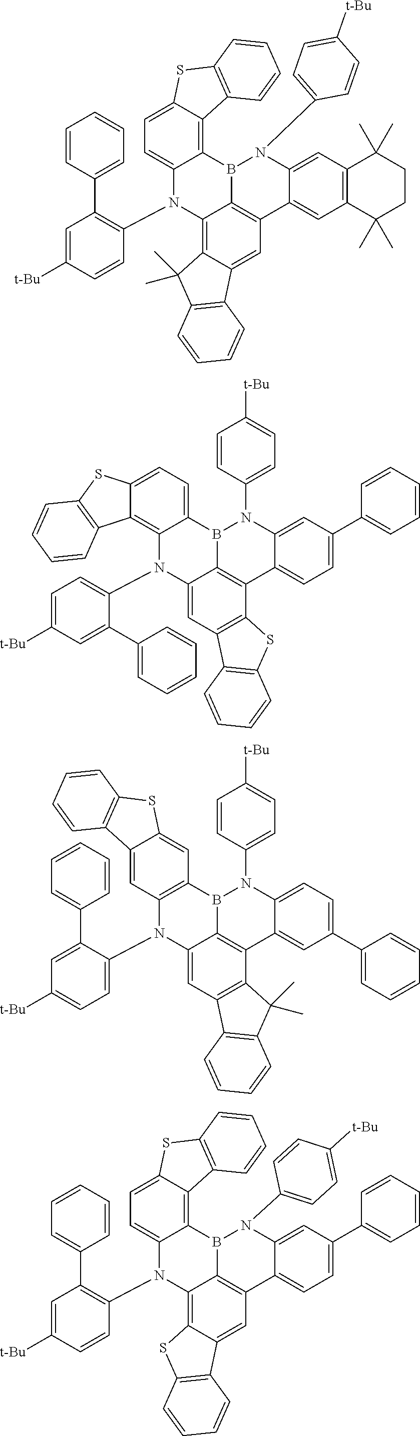 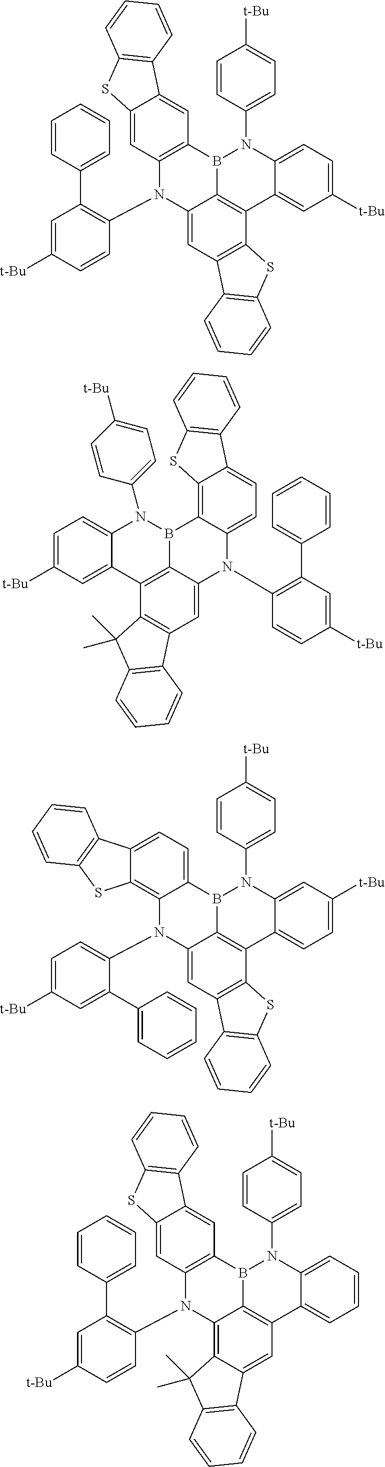 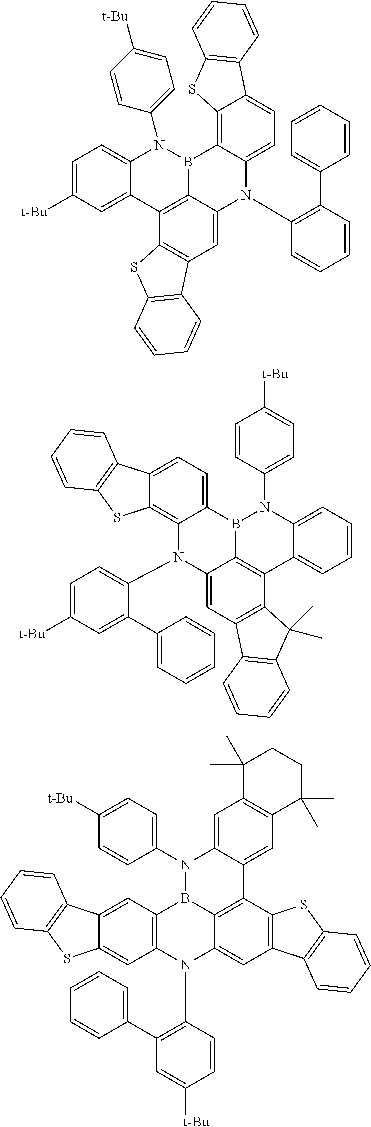 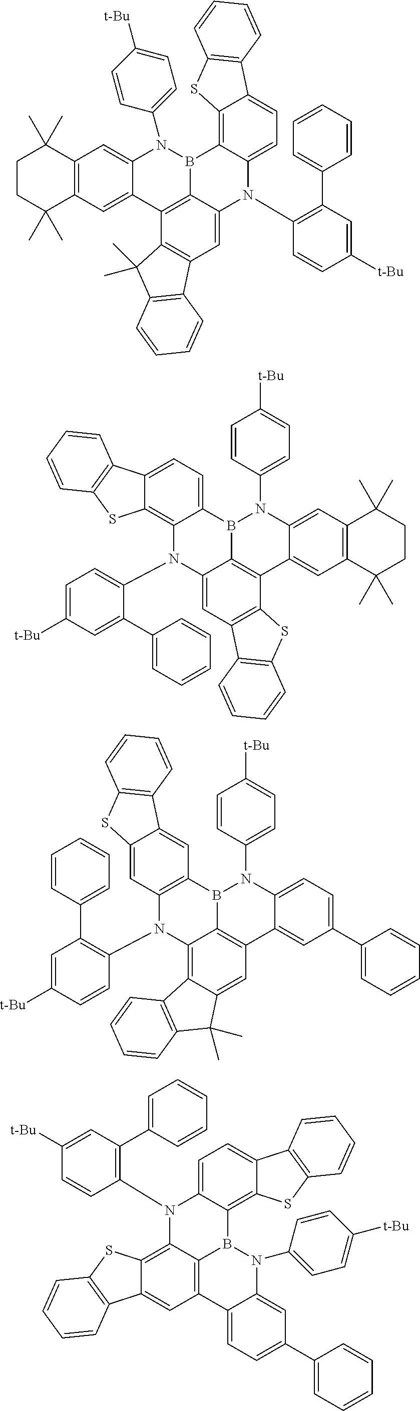 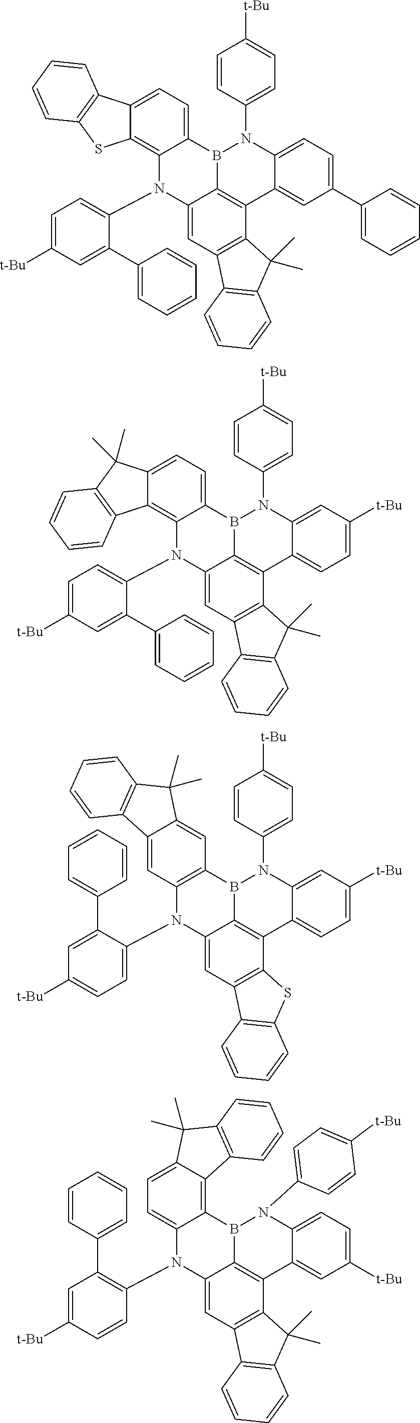 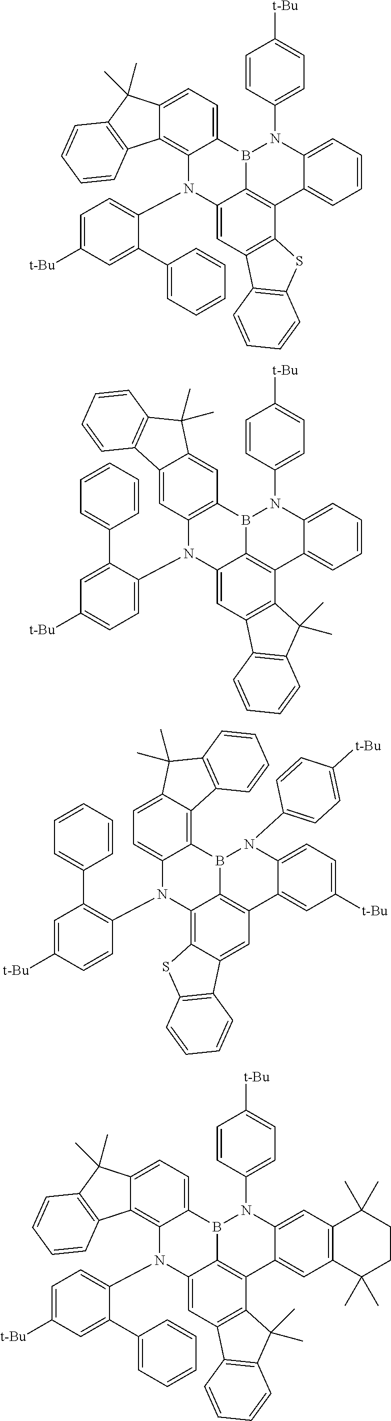 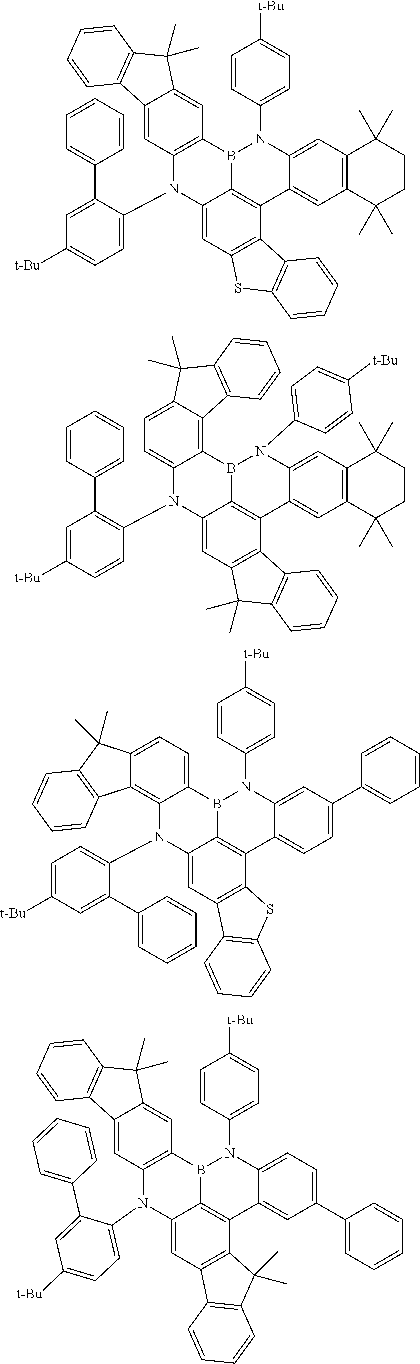 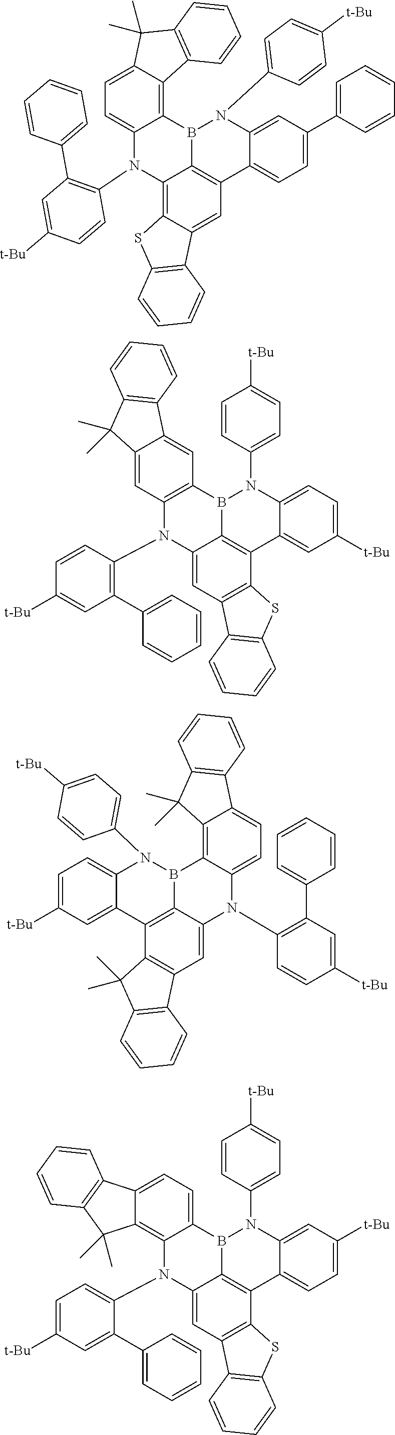 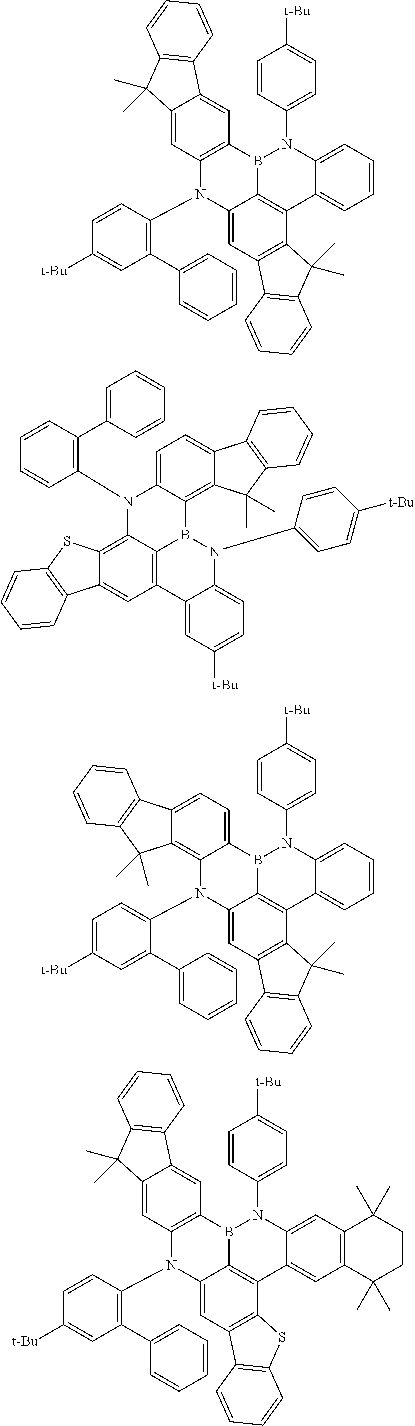 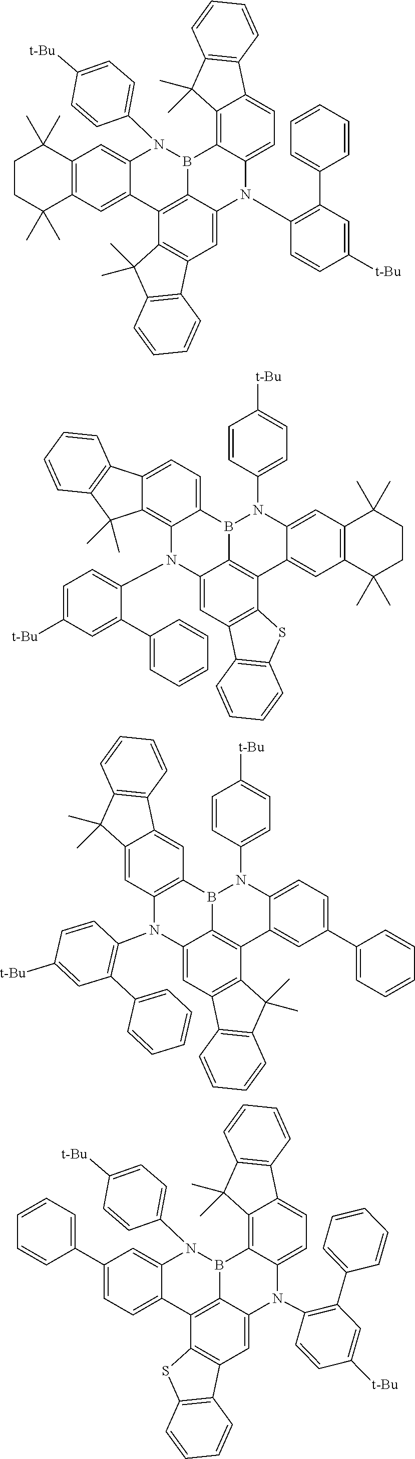 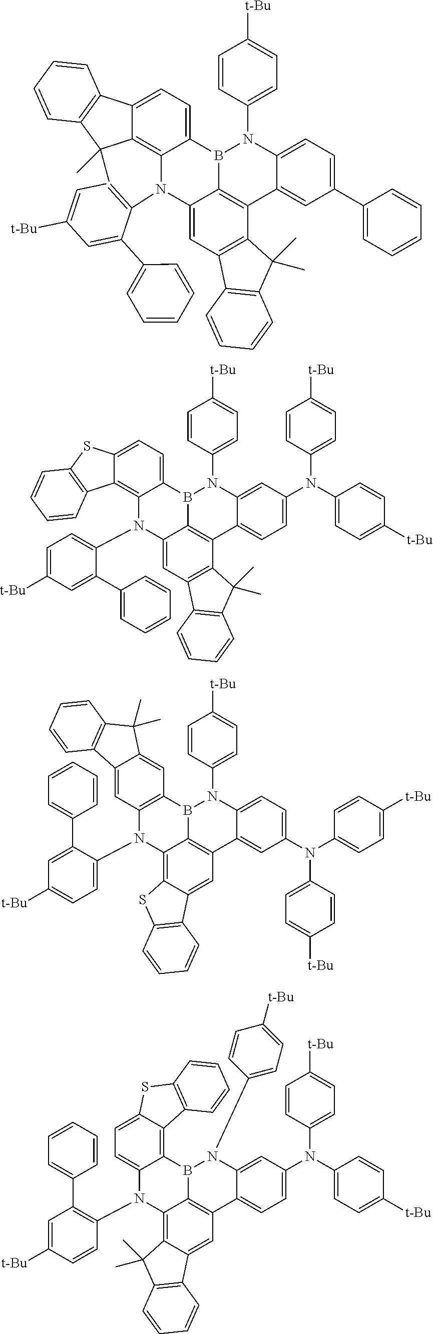 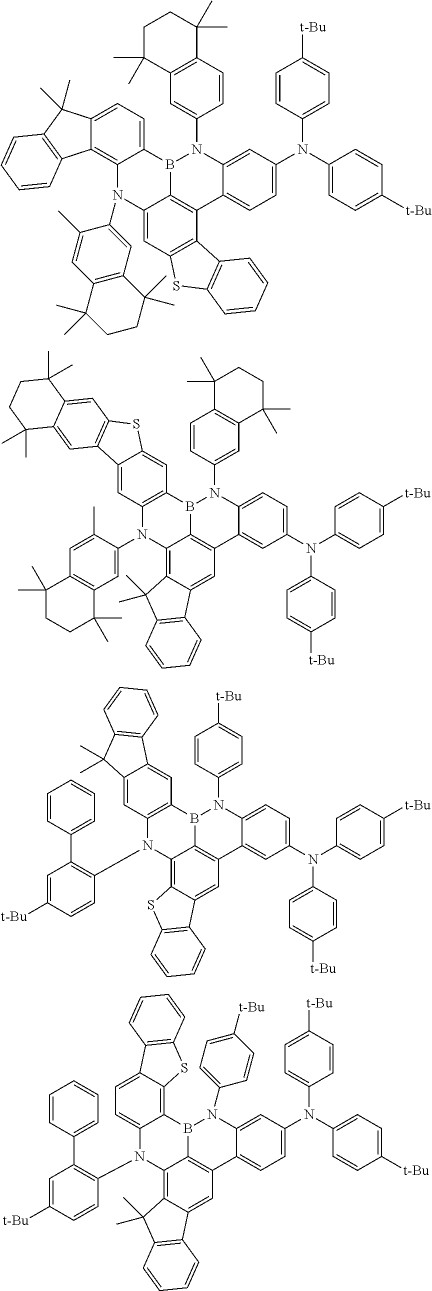 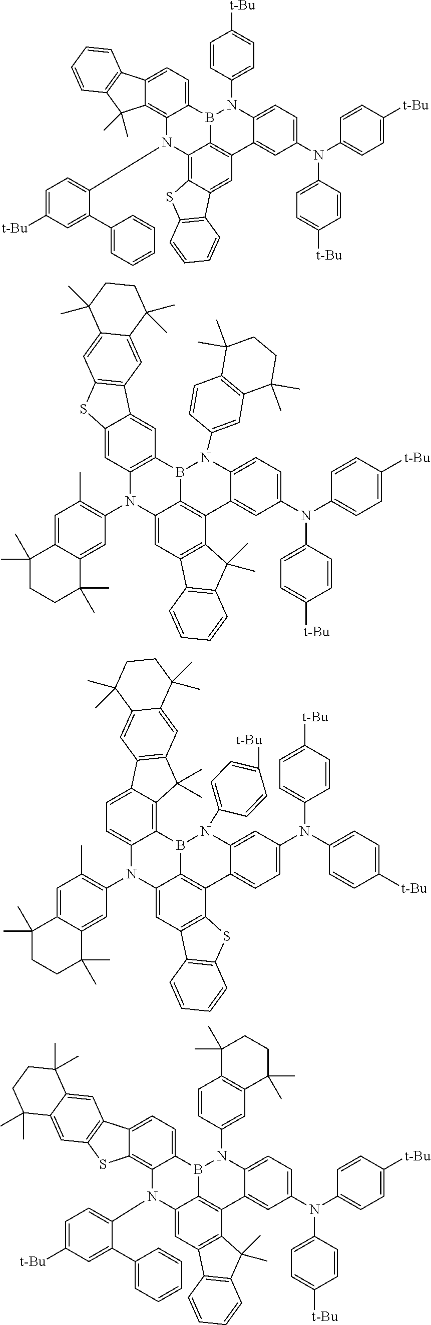 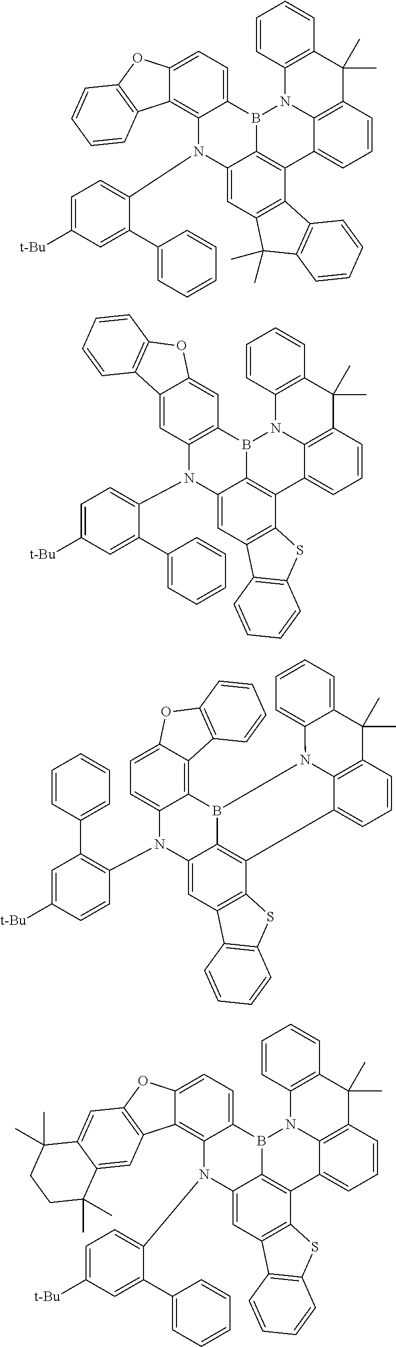 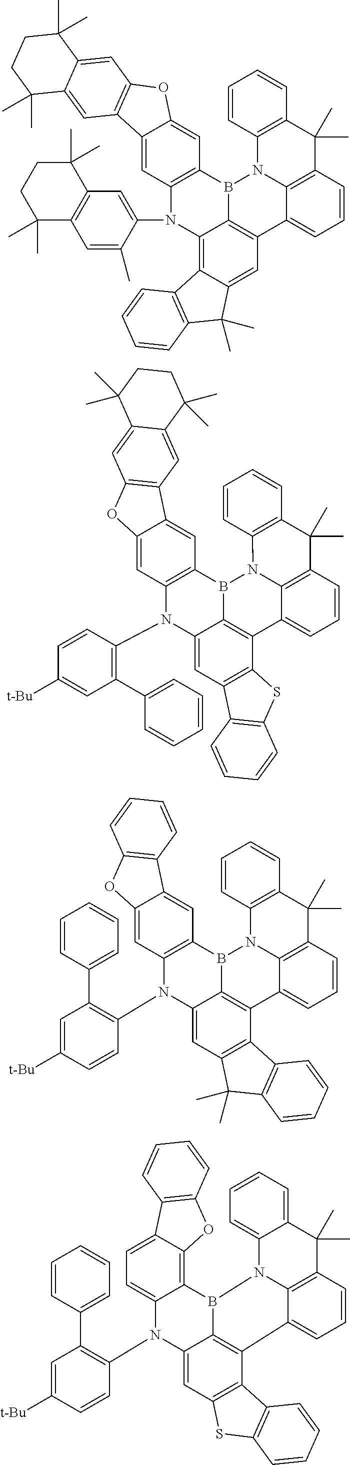 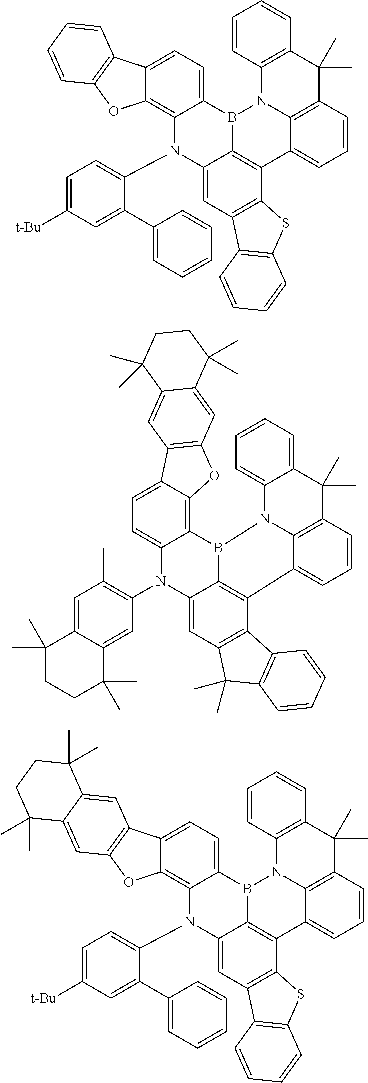 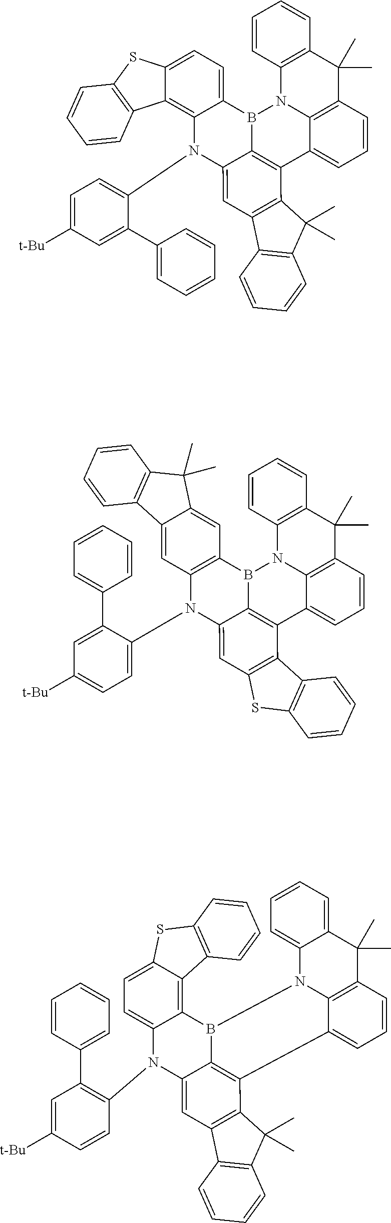 [SMILES: CC(C)(C)c1ccc(N2c3cc4c(c5c3B(c3ccc6sc7ccccc7c6c32)N2c3ccccc3C(C)(C)c3cccc-5c32)C(C)(C)c2ccccc2-4)c(-c2ccccc2)c1 ; CC(C)(C)c1ccc(N2c3cc4c(cc3B3c5c2cc2sc6ccccc6c2c5-c2cccc5c2N3c2ccccc2C5(C)C)C(C)(C)c2ccccc2-4)c(-c2ccccc2)c1 ; CC(C)(C)c1ccc(N2c3cc4c(c5c3B(c3c2ccc2sc6ccccc6c32)N2c3ccccc3C(C)(C)c3cccc-5c32)C(C)(C)c2ccccc2-4)c(-c2ccccc2)c1] 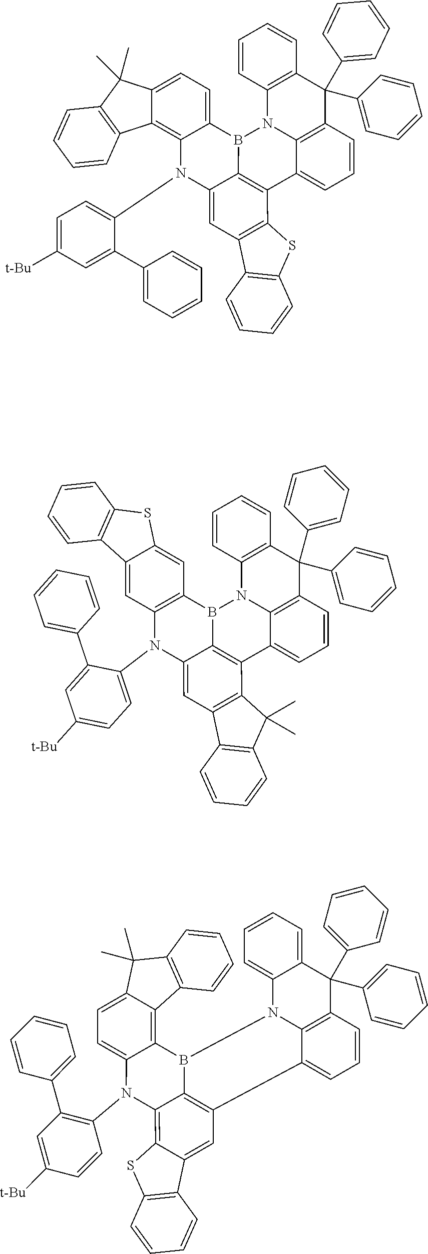 [SMILES: CC(C)(C)c1ccc(N2c3cc4c(sc5ccccc54)c4c3B(c3ccc5c(c32)-c2ccccc2C5(C)C)N2c3ccccc3C(c3ccccc3)(c3ccccc3)c3cccc-4c32)c(-c2ccccc2)c1 ; CC(C)(C)c1ccc(N2c3cc4c(cc3B3c5c2cc2c(c5-c5cccc6c5N3c3ccccc3C6(c3ccccc3)c3ccccc3)C(C)(C)c3ccccc3-2)sc2ccccc24)c(-c2ccccc2)c1 ; CC(C)(C)c1ccc(N2c3ccc4c(c3B3c5c(cc6c(sc7ccccc76)c52)-c2cccc5c2N3c2ccccc2C5(c2ccccc2)c2ccccc2)-c2ccccc2C4(C)C)c(-c2ccccc2)c1] 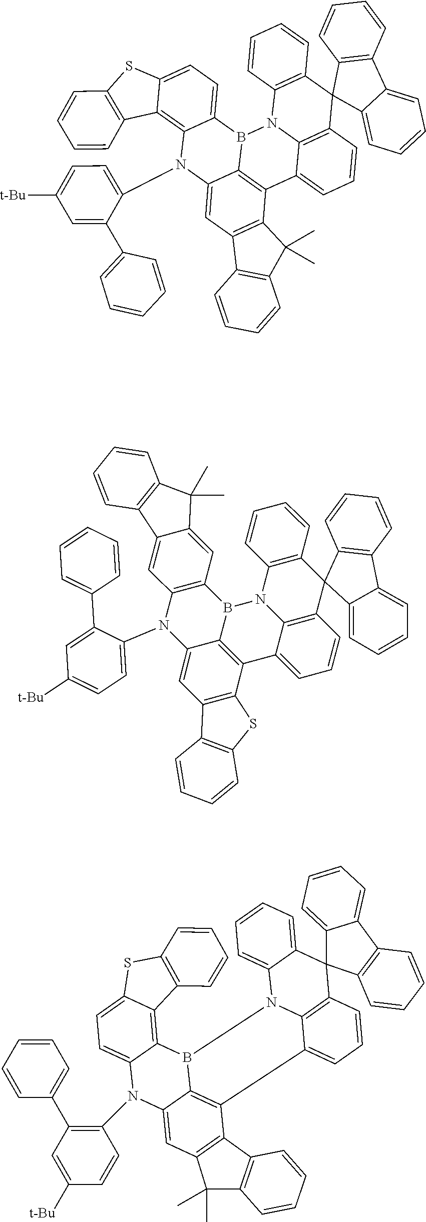 [SMILES: CC(C)(C)c1ccc(N2c3cc4c(c5c3B(c3ccc6sc7ccccc7c6c32)N2c3ccccc3C3(c6ccccc6-c6ccccc63)c3cccc-5c32)C(C)(C)c2ccccc2-4)c(-c2ccccc2)c1 ; CC(C)(C)c1ccc(N2c3cc4c(cc3B3c5c2cc2c(sc6ccccc62)c5-c2cccc5c2N3c2ccccc2C52c3ccccc3-c3ccccc32)C(C)(C)c2ccccc2-4)c(-c2ccccc2)c1 ; CC(C)(C)c1ccc(N2c3cc4c(c5c3B(c3c2ccc2sc6ccccc6c32)N2c3ccccc3C3(c6ccccc6-c6ccccc63)c3cccc-5c32)-c2ccccc2C4(C)C)c(-c2ccccc2)c1] 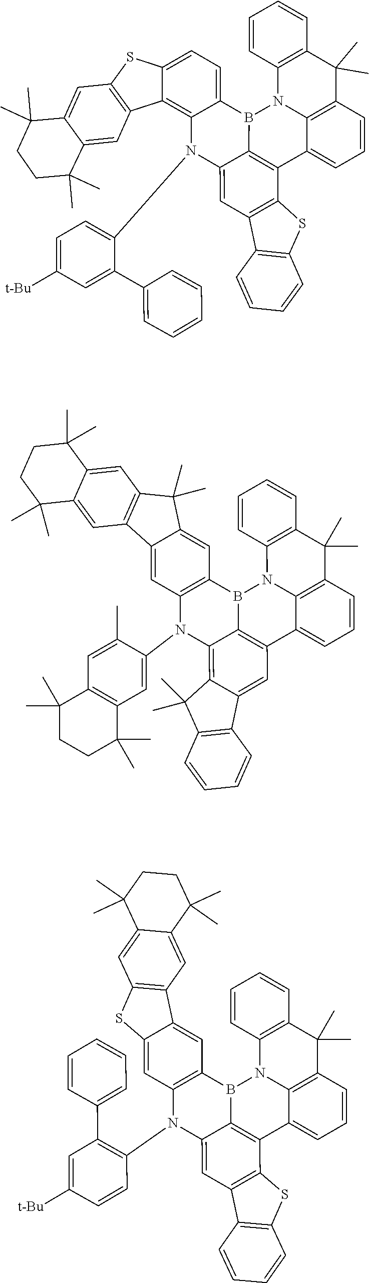 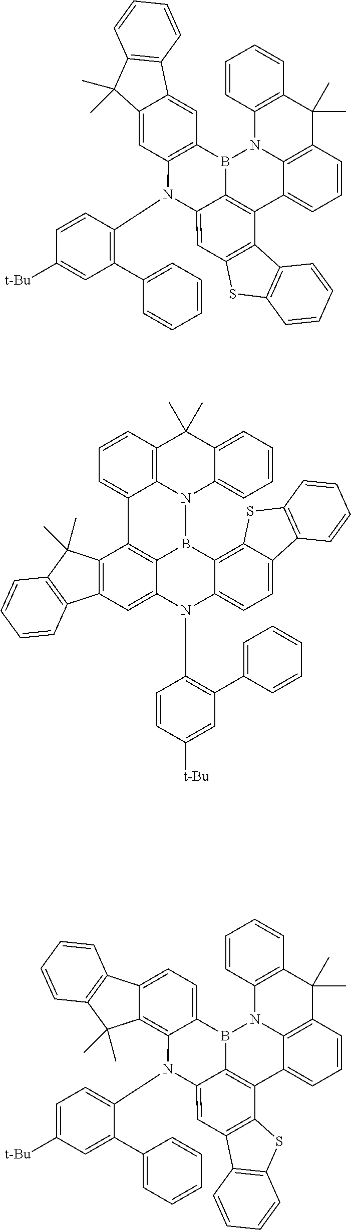 [SMILES: CC(C)(C)c1ccc(N2c3cc4c(cc3B3c5c2cc2sc6ccccc6c2c5-c2cccc5c2N3c2ccccc2C5(C)C)-c2ccccc2C4(C)C)c(-c2ccccc2)c1 ; CC(C)(C)c1ccc(N2c3cc4c(c5c3B(c3c2ccc2c3sc3ccccc32)N2c3ccccc3C(C)(C)c3cccc-5c32)C(C)(C)c2ccccc2-4)c(-c2ccccc2)c1 ; CC(C)(C)c1ccc(N2c3cc4c(sc5ccccc54)c4c3B(c3ccc5c(c32)C(C)(C)c2ccccc2-5)N2c3ccccc3C(C)(C)c3cccc-4c32)c(-c2ccccc2)c1] 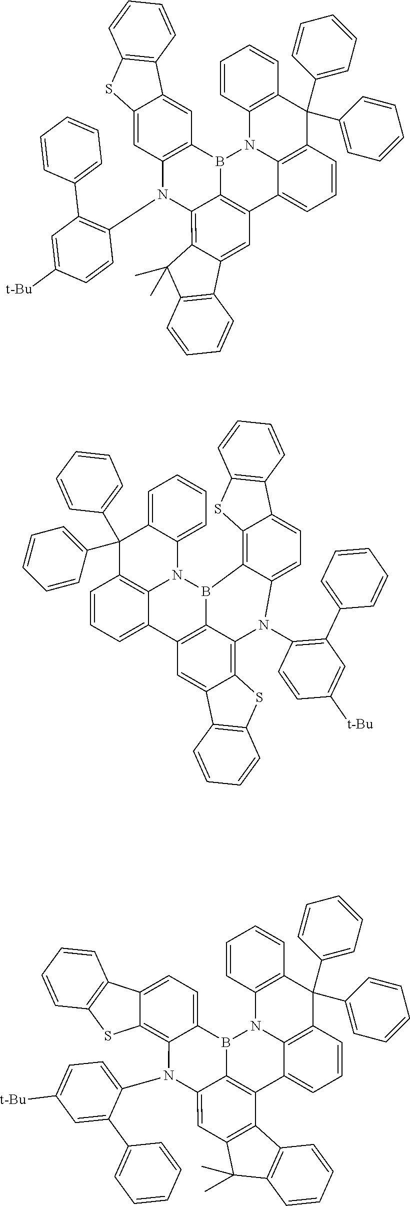 [SMILES: CC(C)(C)c1ccc(N2c3cc4sc5ccccc5c4cc3B3c4c(cc5c(c42)C(C)(C)c2ccccc2-5)-c2cccc4c2N3c2ccccc2C4(c2ccccc2)c2ccccc2)c(-c2ccccc2)c1 ; CC(C)(C)c1ccc(N2c3ccc4c(sc5ccccc54)c3B3c4c(cc5c(sc6ccccc65)c42)-c2cccc4c2N3c2ccccc2C4(c2ccccc2)c2ccccc2)c(-c2ccccc2)c1 ; CC(C)(C)c1ccc(N2c3cc4c(c5c3B(c3ccc6c(sc7ccccc76)c32)N2c3ccccc3C(c3ccccc3)(c3ccccc3)c3cccc-5c32)-c2ccccc2C4(C)C)c(-c2ccccc2)c1] 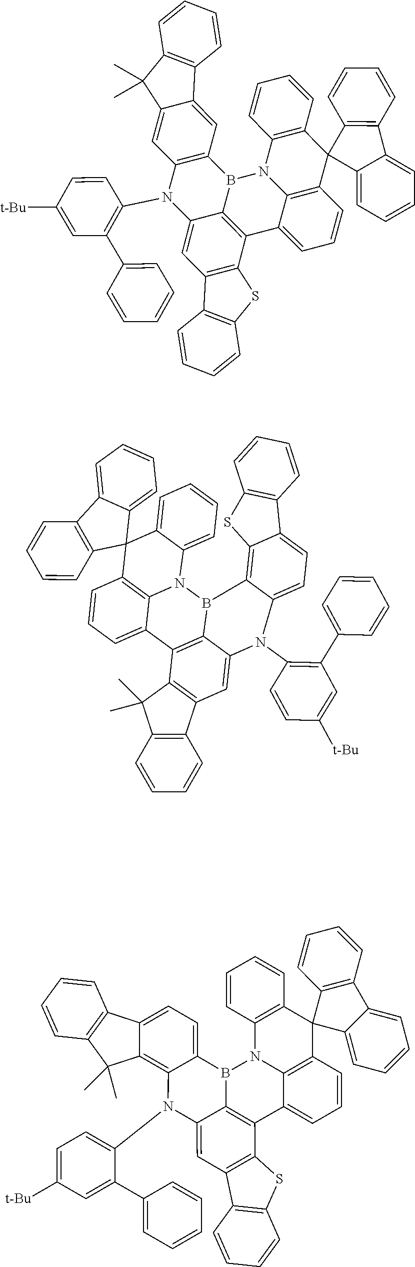 [SMILES: CC(C)(C)c1ccc(N2c3cc4c(cc3B3c5c2cc2c(sc6ccccc62)c5-c2cccc5c2N3c2ccccc2C52c3ccccc3-c3ccccc32)-c2ccccc2C4(C)C)c(-c2ccccc2)c1 ; CC(C)(C)c1ccc(N2c3cc4c(c5c3B(c3c2ccc2c3sc3ccccc32)N2c3ccccc3C3(c6ccccc6-c6ccccc63)c3cccc-5c32)C(C)(C)c2ccccc2-4)c(-c2ccccc2)c1 ; CC(C)(C)c1ccc(N2c3cc4c(sc5ccccc54)c4c3B(c3ccc5c(c32)C(C)(C)c2ccccc2-5)N2c3ccccc3C3(c5ccccc5-c5ccccc53)c3cccc-4c32)c(-c2ccccc2)c1] 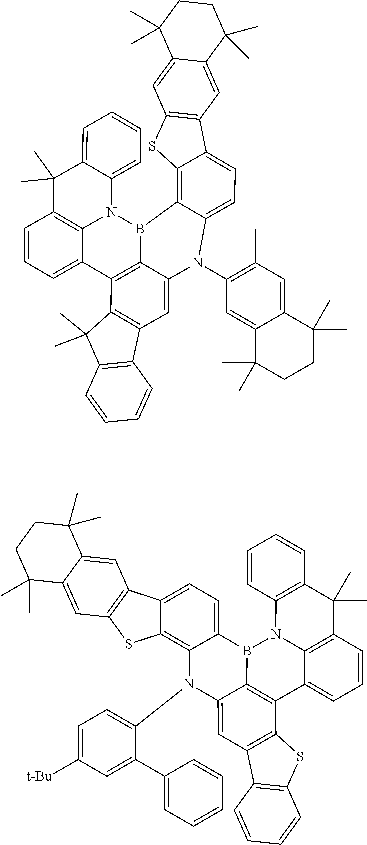 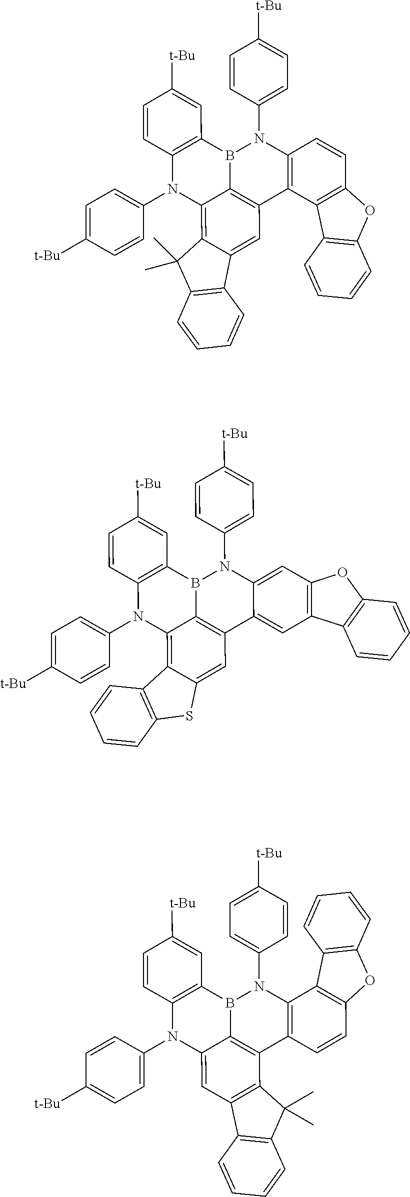 [SMILES: CC(C)(C)c1ccc(N2B3c4cc(C(C)(C)C)ccc4N(c4ccc(C(C)(C)C)cc4)c4c3c(cc3c4C(C)(C)c4ccccc4-3)-c3c2ccc2oc4ccccc4c32)cc1 ; CC(C)(C)c1ccc(N2B3c4cc(C(C)(C)C)ccc4N(c4ccc(C(C)(C)C)cc4)c4c3c(cc3sc5ccccc5c43)-c3cc4c(cc32)oc2ccccc24)cc1 ; CC(C)(C)c1ccc(N2B3c4cc(C(C)(C)C)ccc4N(c4ccc(C(C)(C)C)cc4)c4cc5c(c(c43)-c3ccc4oc6ccccc6c4c32)C(C)(C)c2ccccc2-5)cc1] 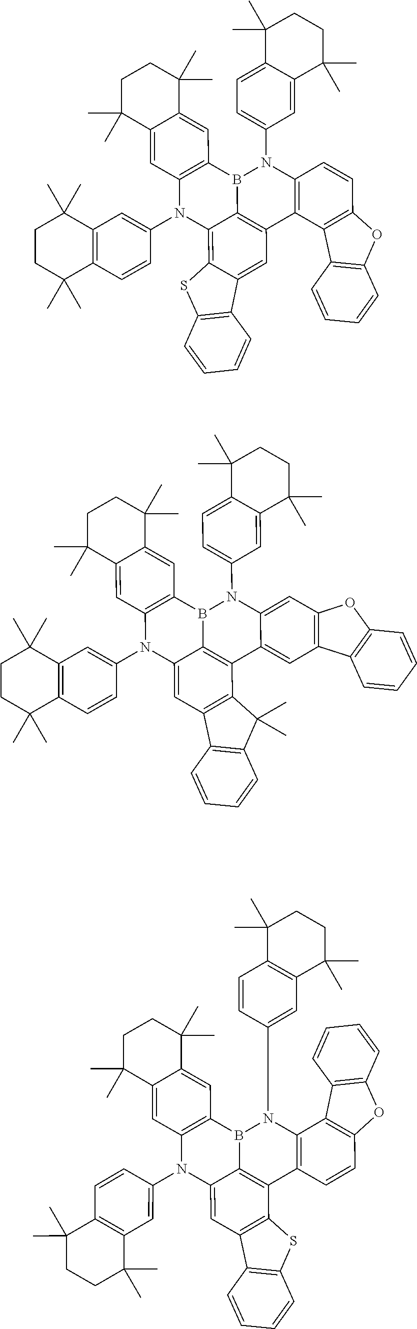 [SMILES: CC1(C)CCC(C)(C)c2cc(N3B4c5cc6c(cc5N(c5ccc7c(c5)C(C)(C)CCC7(C)C)c5c4c(cc4c5sc5ccccc54)-c4c3ccc3oc5ccccc5c43)C(C)(C)CCC6(C)C)ccc21 ; CC1(C)CCC(C)(C)c2cc(N3B4c5cc6c(cc5N(c5ccc7c(c5)C(C)(C)CCC7(C)C)c5cc7c(c(c54)-c4cc5c(cc43)oc3ccccc35)C(C)(C)c3ccccc3-7)C(C)(C)CCC6(C)C)ccc21 ; CC1(C)CCC(C)(C)c2cc(N3B4c5cc6c(cc5N(c5ccc7c(c5)C(C)(C)CCC7(C)C)c5cc7c(sc8ccccc87)c(c54)-c4ccc5oc7ccccc7c5c43)C(C)(C)CCC6(C)C)ccc21] 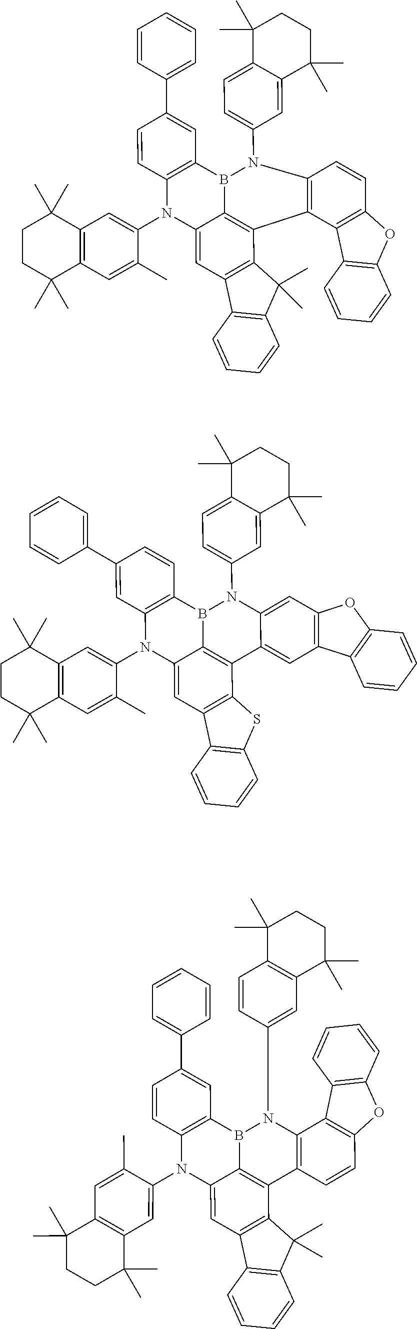 [SMILES: Cc1cc2c(cc1N1c3ccc(-c4ccccc4)cc3B3c4c1cc1c(c4-c4c(ccc5oc6ccccc6c45)N3c3ccc4c(c3)C(C)(C)CCC4(C)C)C(C)(C)c3ccccc3-1)C(C)(C)CCC2(C)C ; Cc1cc2c(cc1N1c3cc(-c4ccccc4)ccc3B3c4c1cc1c(sc5ccccc51)c4-c1cc4c(cc1N3c1ccc3c(c1)C(C)(C)CCC3(C)C)oc1ccccc14)C(C)(C)CCC2(C)C ; Cc1cc2c(cc1N1c3ccc(-c4ccccc4)cc3B3c4c1cc1c(c4-c4ccc5oc6ccccc6c5c4N3c3ccc4c(c3)C(C)(C)CCC4(C)C)C(C)(C)c3ccccc3-1)C(C)(C)CCC2(C)C] 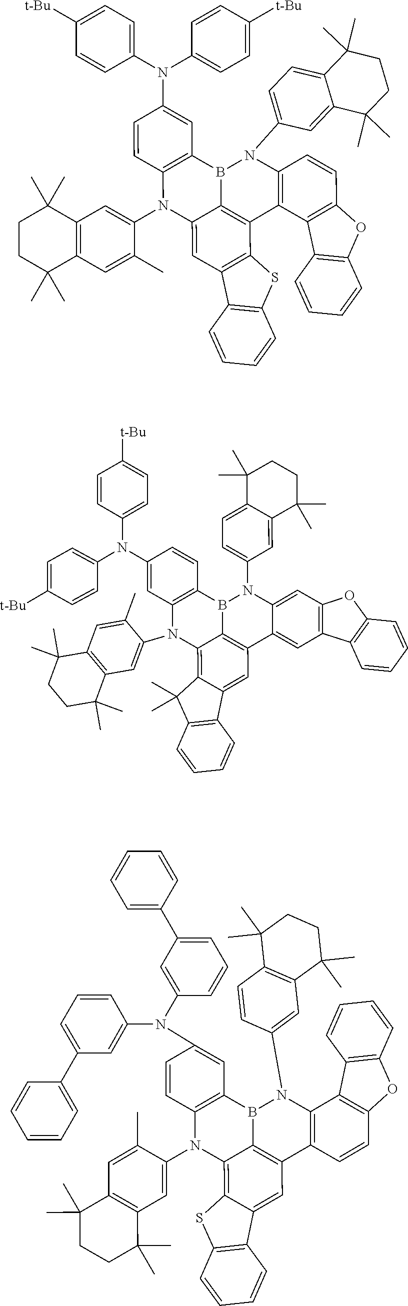 [SMILES: Cc1cc2c(cc1N1c3ccc(N(c4ccc(C(C)(C)C)cc4)c4ccc(C(C)(C)C)cc4)cc3B3c4c1cc1c(sc5ccccc51)c4-c1c(ccc4oc5ccccc5c14)N3c1ccc3c(c1)C(C)(C)CCC3(C)C)C(C)(C)CCC2(C)C ; Cc1cc2c(cc1N1c3cc(N(c4ccc(C(C)(C)C)cc4)c4ccc(C(C)(C)C)cc4)ccc3B3c4c(cc5c(c41)C(C)(C)c1ccccc1-5)-c1cc4c(cc1N3c1ccc3c(c1)C(C)(C)CCC3(C)C)oc1ccccc14)C(C)(C)CCC2(C)C ; Cc1cc2c(cc1N1c3ccc(N(c4cccc(-c5ccccc5)c4)c4cccc(-c5ccccc5)c4)cc3B3c4c(cc5c(sc6ccccc65)c41)-c1ccc4oc5ccccc5c4c1N3c1ccc3c(c1)C(C)(C)CCC3(C)C)C(C)(C)CCC2(C)C] 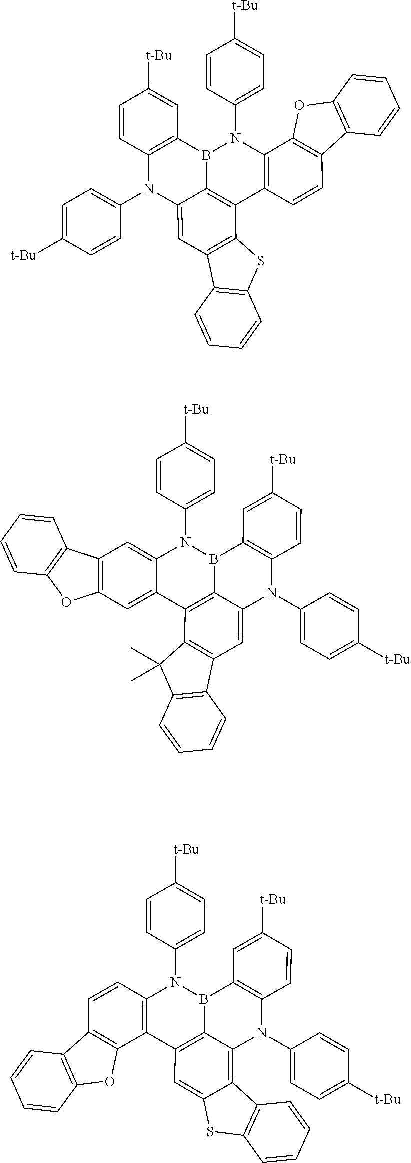 [SMILES: CC(C)(C)c1ccc(N2B3c4cc(C(C)(C)C)ccc4N(c4ccc(C(C)(C)C)cc4)c4cc5c(sc6ccccc65)c(c43)-c3ccc4c(oc5ccccc54)c32)cc1 ; CC(C)(C)c1ccc(N2B3c4cc(C(C)(C)C)ccc4N(c4ccc(C(C)(C)C)cc4)c4cc5c(c(c43)-c3cc4oc6ccccc6c4cc32)C(C)(C)c2ccccc2-5)cc1 ; CC(C)(C)c1ccc(N2B3c4cc(C(C)(C)C)ccc4N(c4ccc(C(C)(C)C)cc4)c4c3c(cc3sc5ccccc5c43)-c3c2ccc2c3oc3ccccc32)cc1] 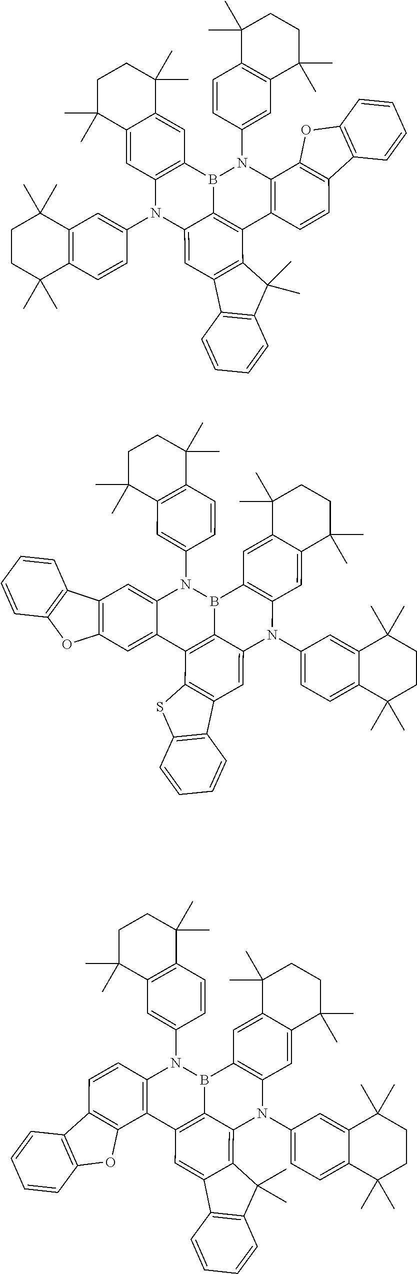 [SMILES: CC1(C)CCC(C)(C)c2cc(N3B4c5cc6c(cc5N(c5ccc7c(c5)C(C)(C)CCC7(C)C)c5cc7c(c(c54)-c4ccc5c(oc8ccccc85)c43)C(C)(C)c3ccccc3-7)C(C)(C)CCC6(C)C)ccc21 ; CC1(C)CCC(C)(C)c2cc(N3B4c5cc6c(cc5N(c5ccc7c(c5)C(C)(C)CCC7(C)C)c5cc7c(sc8ccccc87)c(c54)-c4cc5oc7ccccc7c5cc43)C(C)(C)CCC6(C)C)ccc21 ; CC1(C)CCC(C)(C)c2cc(N3B4c5cc6c(cc5N(c5ccc7c(c5)C(C)(C)CCC7(C)C)c5c4c(cc4c5C(C)(C)c5ccccc5-4)-c4c3ccc3c4oc4ccccc43)C(C)(C)CCC6(C)C)ccc21] 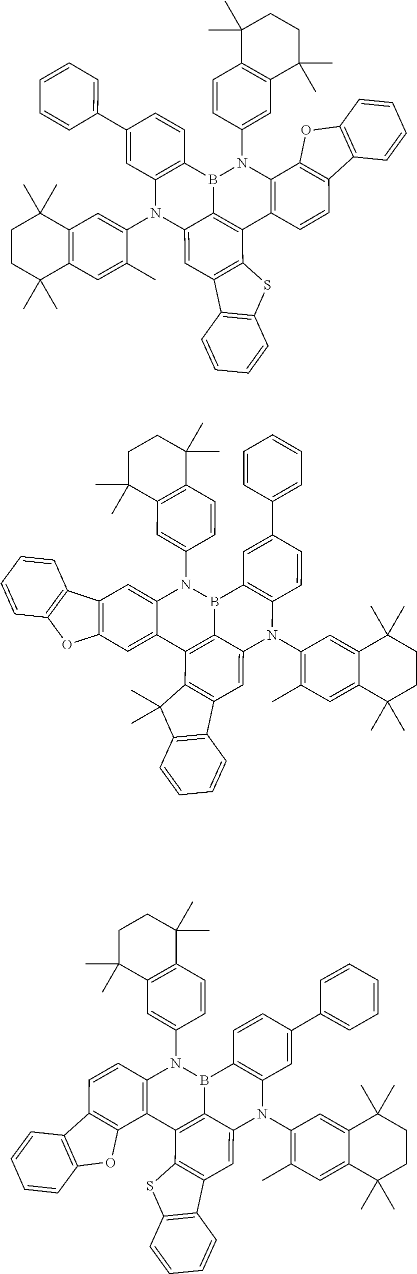 [SMILES: Cc1cc2c(cc1N1c3cc(-c4ccccc4)ccc3B3c4c1cc1c(sc5ccccc51)c4-c1ccc4c(oc5ccccc54)c1N3c1ccc3c(c1)C(C)(C)CCC3(C)C)C(C)(C)CCC2(C)C ; Cc1cc2c(cc1N1c3ccc(-c4ccccc4)cc3B3c4c1cc1c(c4-c4cc5oc6ccccc6c5cc4N3c3ccc4c(c3)C(C)(C)CCC4(C)C)C(C)(C)c3ccccc3-1)C(C)(C)CCC2(C)C ; Cc1cc2c(cc1N1c3cc(-c4ccccc4)ccc3B3c4c1cc1c(sc5ccccc51)c4-c1c(ccc4c1oc1ccccc14)N3c1ccc3c(c1)C(C)(C)CCC3(C)C)C(C)(C)CCC2(C)C] 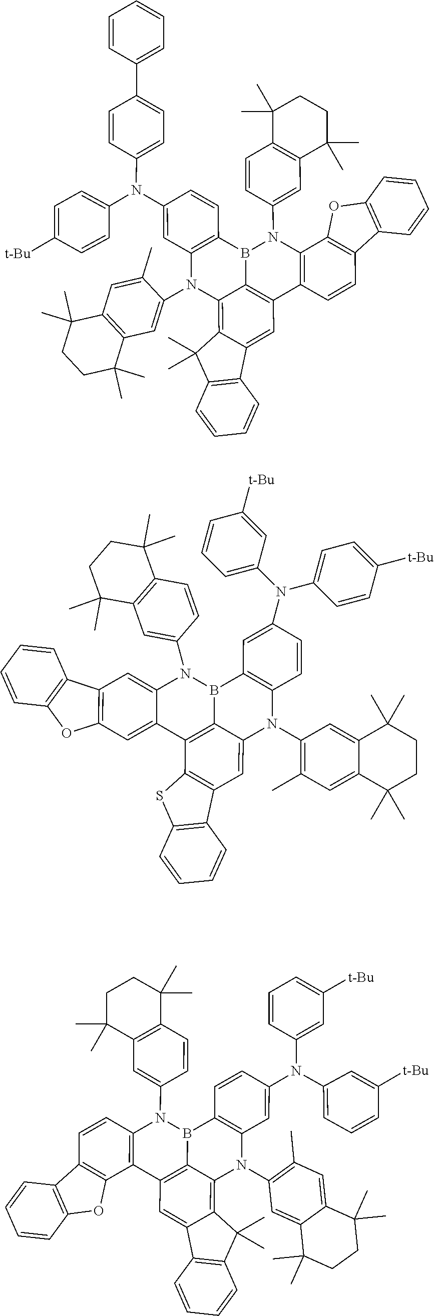 [SMILES: Cc1cc2c(cc1N1c3cc(N(c4ccc(-c5ccccc5)cc4)c4ccc(C(C)(C)C)cc4)ccc3B3c4c(cc5c(c41)C(C)(C)c1ccccc1-5)-c1ccc4c(oc5ccccc54)c1N3c1ccc3c(c1)C(C)(C)CCC3(C)C)C(C)(C)CCC2(C)C ; Cc1cc2c(cc1N1c3ccc(N(c4ccc(C(C)(C)C)cc4)c4cccc(C(C)(C)C)c4)cc3B3c4c1cc1c(sc5ccccc51)c4-c1cc4oc5ccccc5c4cc1N3c1ccc3c(c1)C(C)(C)CCC3(C)C)C(C)(C)CCC2(C)C ; Cc1cc2c(cc1N1c3cc(N(c4cccc(C(C)(C)C)c4)c4cccc(C(C)(C)C)c4)ccc3B3c4c(cc5c(c41)C(C)(C)c1ccccc1-5)-c1c(ccc4c1oc1ccccc14)N3c1ccc3c(c1)C(C)(C)CCC3(C)C)C(C)(C)CCC2(C)C] 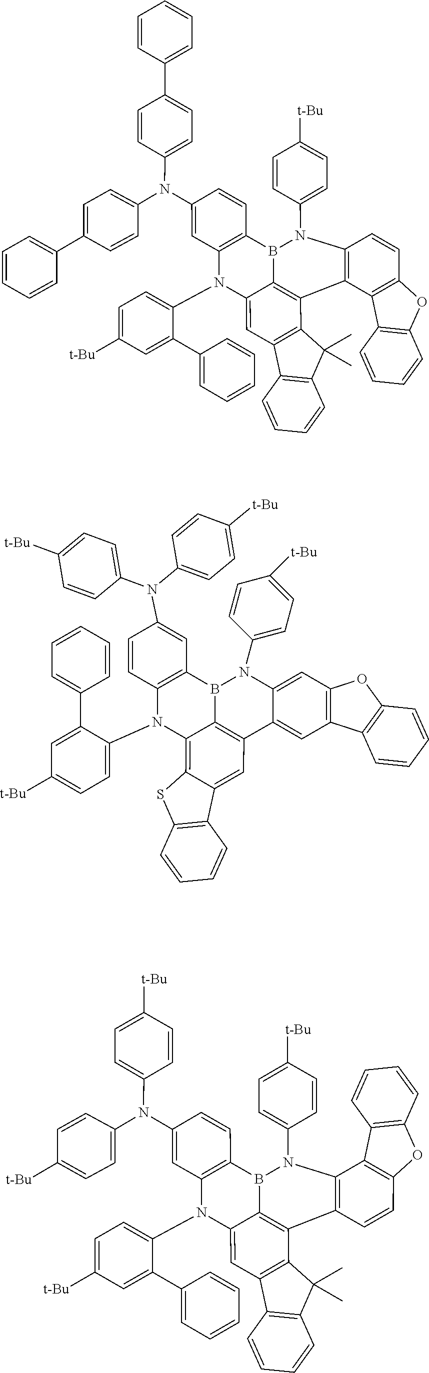 [SMILES: CC(C)(C)c1ccc(N2B3c4ccc(N(c5ccc(-c6ccccc6)cc5)c5ccc(-c6ccccc6)cc5)cc4N(c4ccc(C(C)(C)C)cc4-c4ccccc4)c4cc5c(c(c43)-c3c2ccc2oc4ccccc4c32)C(C)(C)c2ccccc2-5)cc1 ; CC(C)(C)c1ccc(N2B3c4cc(N(c5ccc(C(C)(C)C)cc5)c5ccc(C(C)(C)C)cc5)ccc4N(c4ccc(C(C)(C)C)cc4-c4ccccc4)c4c3c(cc3c4sc4ccccc43)-c3cc4c(cc32)oc2ccccc24)cc1 ; CC(C)(C)c1ccc(N2B3c4ccc(N(c5ccc(C(C)(C)C)cc5)c5ccc(C(C)(C)C)cc5)cc4N(c4ccc(C(C)(C)C)cc4-c4ccccc4)c4cc5c(c(c43)-c3ccc4oc6ccccc6c4c32)C(C)(C)c2ccccc2-5)cc1] 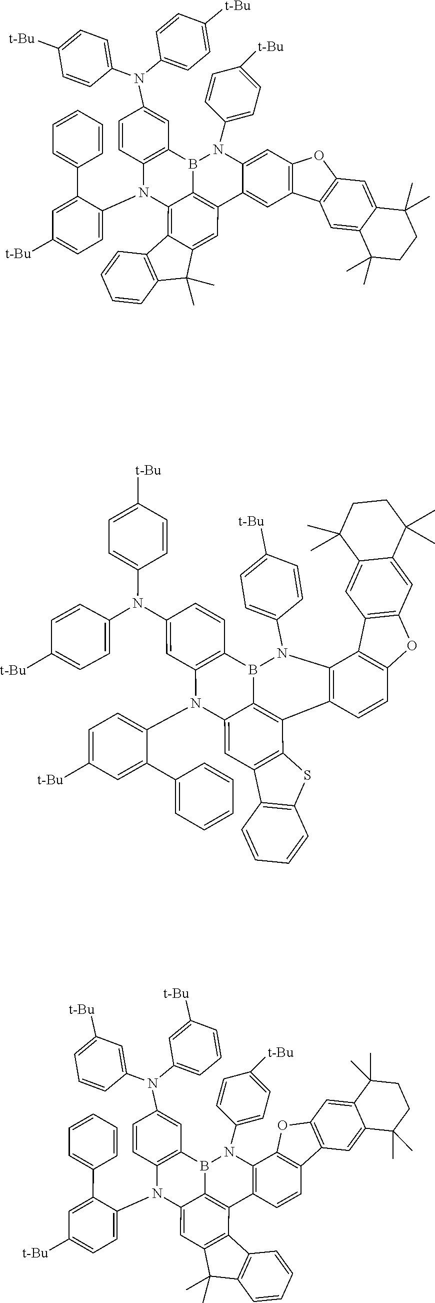 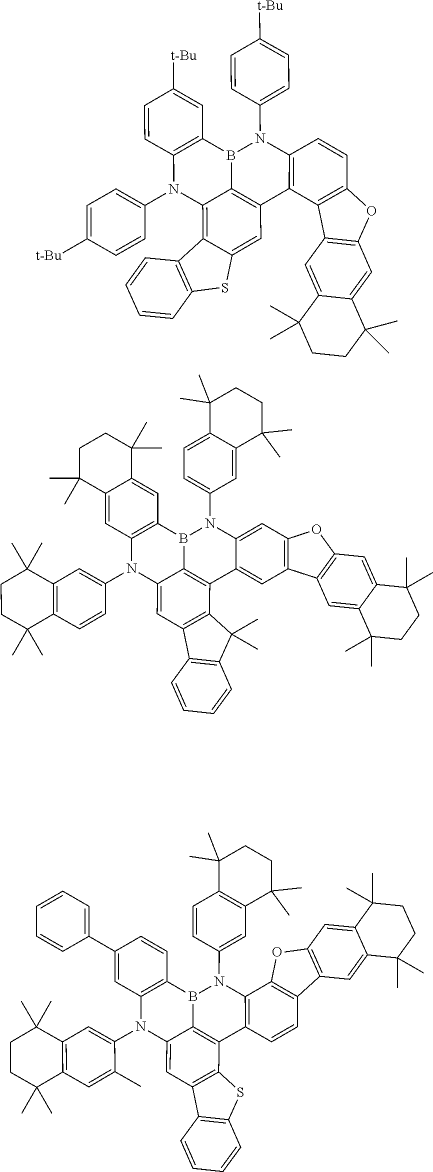 [SMILES: CC(C)(C)c1ccc(N2B3c4cc(C(C)(C)C)ccc4N(c4ccc(C(C)(C)C)cc4)c4c3c(cc3sc5ccccc5c43)-c3c2ccc2oc4cc5c(cc4c32)C(C)(C)CCC5(C)C)cc1 ; CC1(C)CCC(C)(C)c2cc(N3B4c5cc6c(cc5N(c5ccc7c(c5)C(C)(C)CCC7(C)C)c5cc7c(c(c54)-c4cc5c(cc43)oc3cc4c(cc35)C(C)(C)CCC4(C)C)C(C)(C)c3ccccc3-7)C(C)(C)CCC6(C)C)ccc21 ; Cc1cc2c(cc1N1c3cc(-c4ccccc4)ccc3B3c4c1cc1c(sc5ccccc51)c4-c1ccc4c(oc5cc6c(cc54)C(C)(C)CCC6(C)C)c1N3c1ccc3c(c1)C(C)(C)CCC3(C)C)C(C)(C)CCC2(C)C] 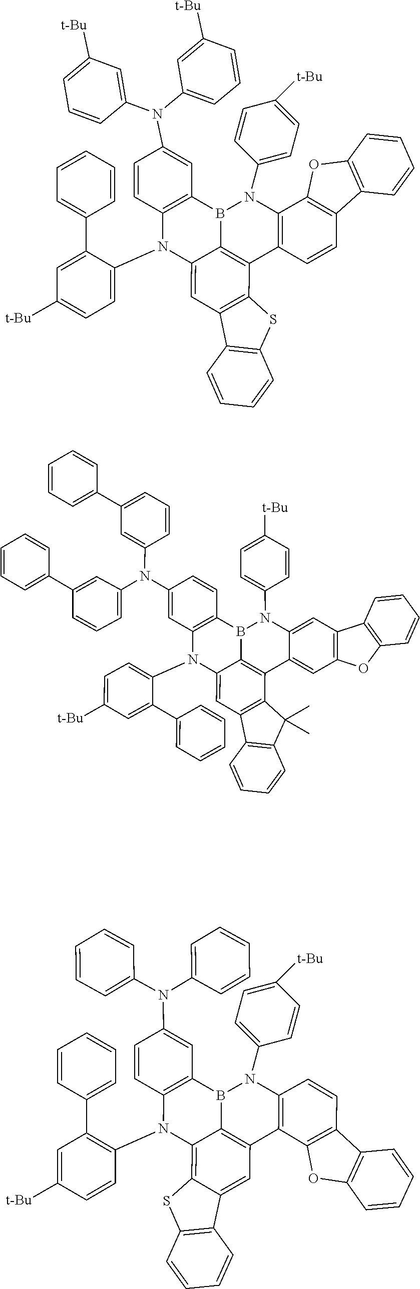 [SMILES: CC(C)(C)c1ccc(N2B3c4cc(N(c5cccc(C(C)(C)C)c5)c5cccc(C(C)(C)C)c5)ccc4N(c4ccc(C(C)(C)C)cc4-c4ccccc4)c4cc5c(sc6ccccc65)c(c43)-c3ccc4c(oc5ccccc54)c32)cc1 ; CC(C)(C)c1ccc(N2B3c4ccc(N(c5cccc(-c6ccccc6)c5)c5cccc(-c6ccccc6)c5)cc4N(c4ccc(C(C)(C)C)cc4-c4ccccc4)c4cc5c(c(c43)-c3cc4oc6ccccc6c4cc32)C(C)(C)c2ccccc2-5)cc1 ; CC(C)(C)c1ccc(N2B3c4cc(N(c5ccccc5)c5ccccc5)ccc4N(c4ccc(C(C)(C)C)cc4-c4ccccc4)c4c3c(cc3c4sc4ccccc43)-c3c2ccc2c3oc3ccccc32)cc1] 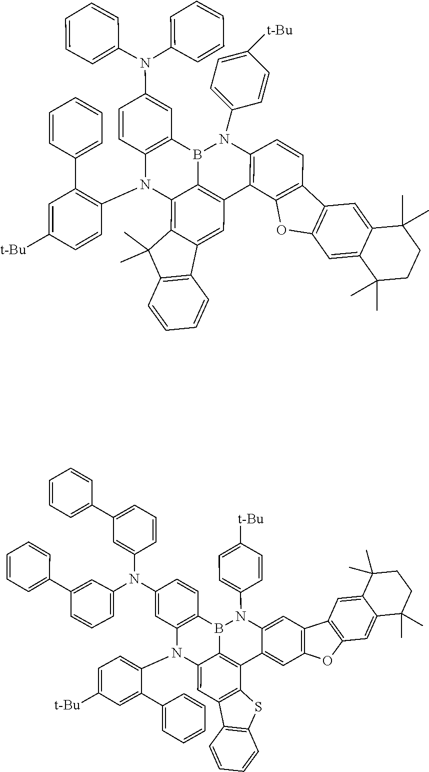 [SMILES: CC(C)(C)c1ccc(N2B3c4cc(N(c5ccccc5)c5ccccc5)ccc4N(c4ccc(C(C)(C)C)cc4-c4ccccc4)c4c3c(cc3c4C(C)(C)c4ccccc4-3)-c3c2ccc2c3oc3cc4c(cc32)C(C)(C)CCC4(C)C)cc1 ; CC(C)(C)c1ccc(N2B3c4ccc(N(c5cccc(-c6ccccc6)c5)c5cccc(-c6ccccc6)c5)cc4N(c4ccc(C(C)(C)C)cc4-c4ccccc4)c4cc5c(sc6ccccc65)c(c43)-c3cc4oc5cc6c(cc5c4cc32)C(C)(C)CCC6(C)C)cc1] 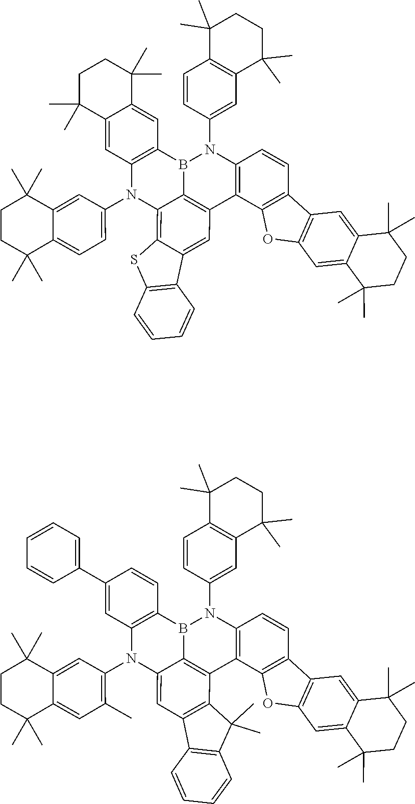 [SMILES: CC1(C)CCC(C)(C)c2cc(N3B4c5cc6c(cc5N(c5ccc7c(c5)C(C)(C)CCC7(C)C)c5c4c(cc4c5sc5ccccc54)-c4c3ccc3c4oc4cc5c(cc43)C(C)(C)CCC5(C)C)C(C)(C)CCC6(C)C)ccc21 ; Cc1cc2c(cc1N1c3cc(-c4ccccc4)ccc3B3c4c1cc1c(c4-c4c(ccc5c4oc4cc6c(cc45)C(C)(C)CCC6(C)C)N3c3ccc4c(c3)C(C)(C)CCC4(C)C)C(C)(C)c3ccccc3-1)C(C)(C)CCC2(C)C] 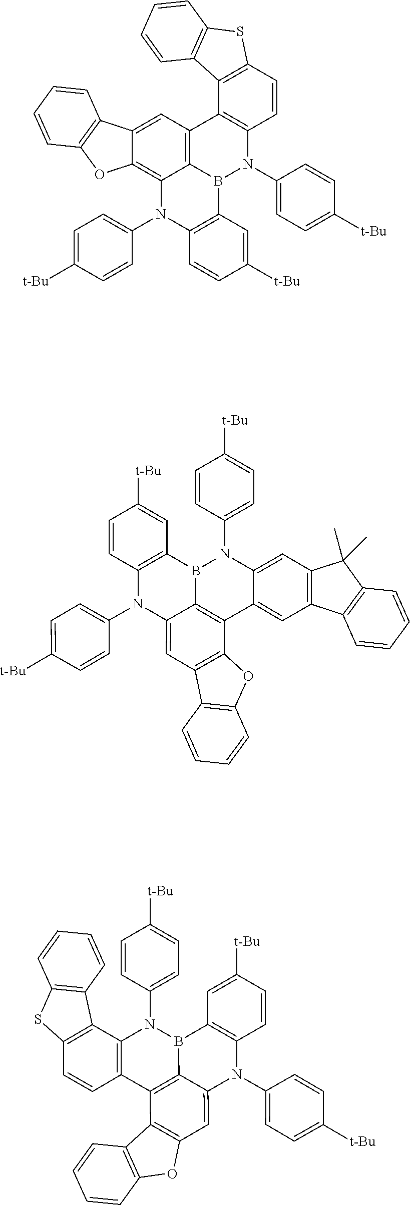 [SMILES: CC(C)(C)c1ccc(N2B3c4cc(C(C)(C)C)ccc4N(c4ccc(C(C)(C)C)cc4)c4c3c(cc3c4oc4ccccc43)-c3c2ccc2sc4ccccc4c32)cc1 ; CC(C)(C)c1ccc(N2B3c4cc(C(C)(C)C)ccc4N(c4ccc(C(C)(C)C)cc4)c4cc5c(oc6ccccc65)c(c43)-c3cc4c(cc32)C(C)(C)c2ccccc2-4)cc1 ; CC(C)(C)c1ccc(N2B3c4cc(C(C)(C)C)ccc4N(c4ccc(C(C)(C)C)cc4)c4cc5oc6ccccc6c5c(c43)-c3ccc4sc5ccccc5c4c32)cc1] 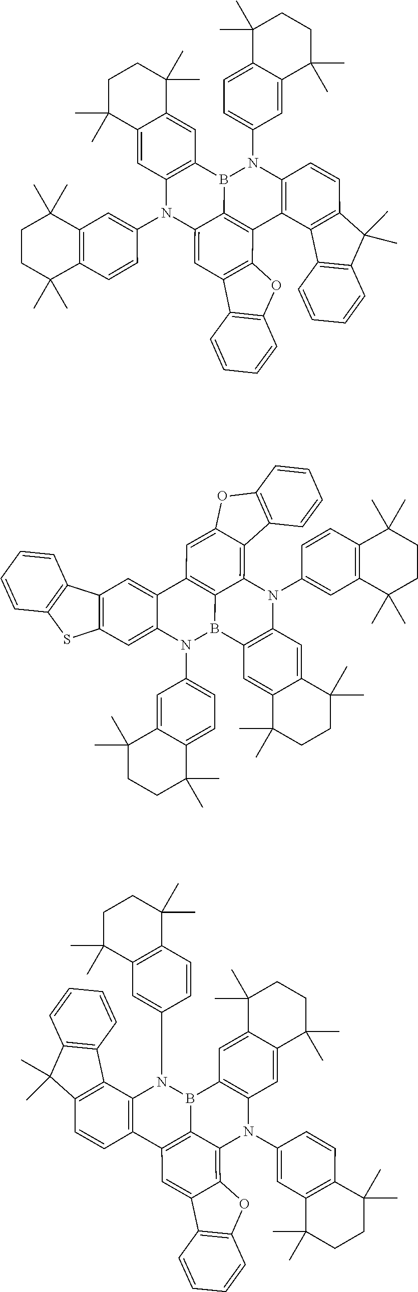 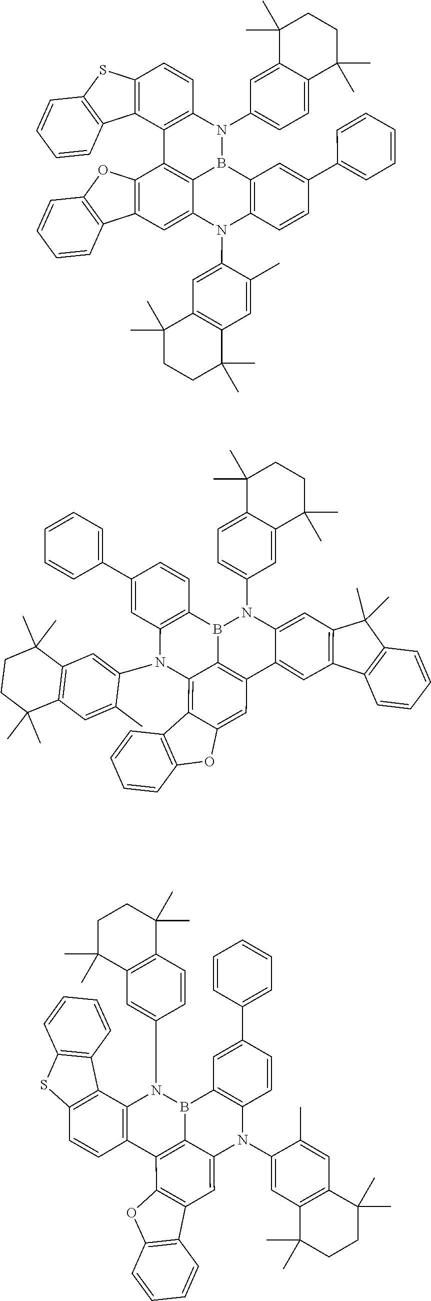 [SMILES: Cc1cc2c(cc1N1c3ccc(-c4ccccc4)cc3B3c4c1cc1c(oc5ccccc51)c4-c1c(ccc4sc5ccccc5c14)N3c1ccc3c(c1)C(C)(C)CCC3(C)C)C(C)(C)CCC2(C)C ; Cc1cc2c(cc1N1c3cc(-c4ccccc4)ccc3B3c4c(cc5oc6ccccc6c5c41)-c1cc4c(cc1N3c1ccc3c(c1)C(C)(C)CCC3(C)C)C(C)(C)c1ccccc1-4)C(C)(C)CCC2(C)C ; Cc1cc2c(cc1N1c3ccc(-c4ccccc4)cc3B3c4c1cc1c(oc5ccccc51)c4-c1ccc4sc5ccccc5c4c1N3c1ccc3c(c1)C(C)(C)CCC3(C)C)C(C)(C)CCC2(C)C] 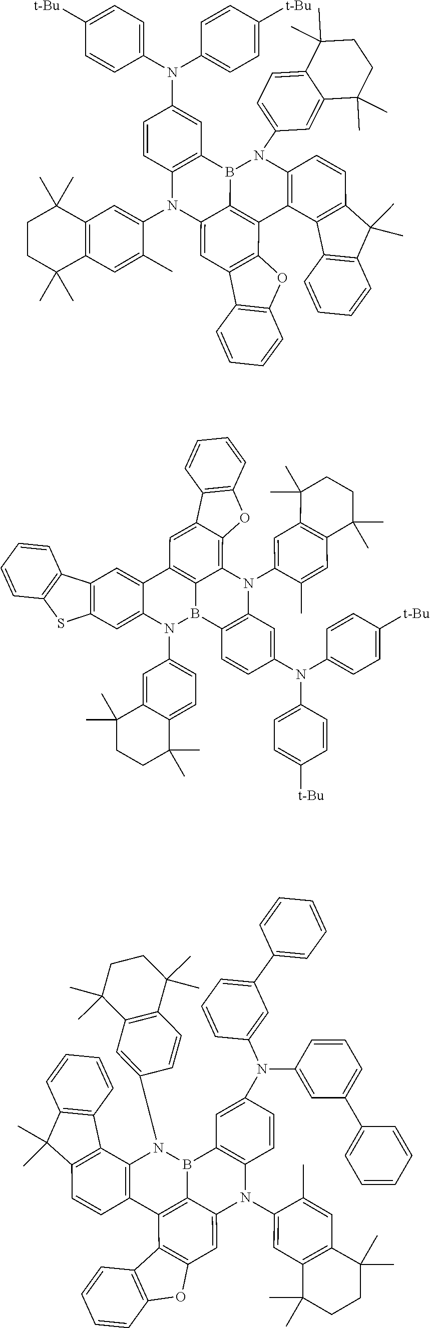 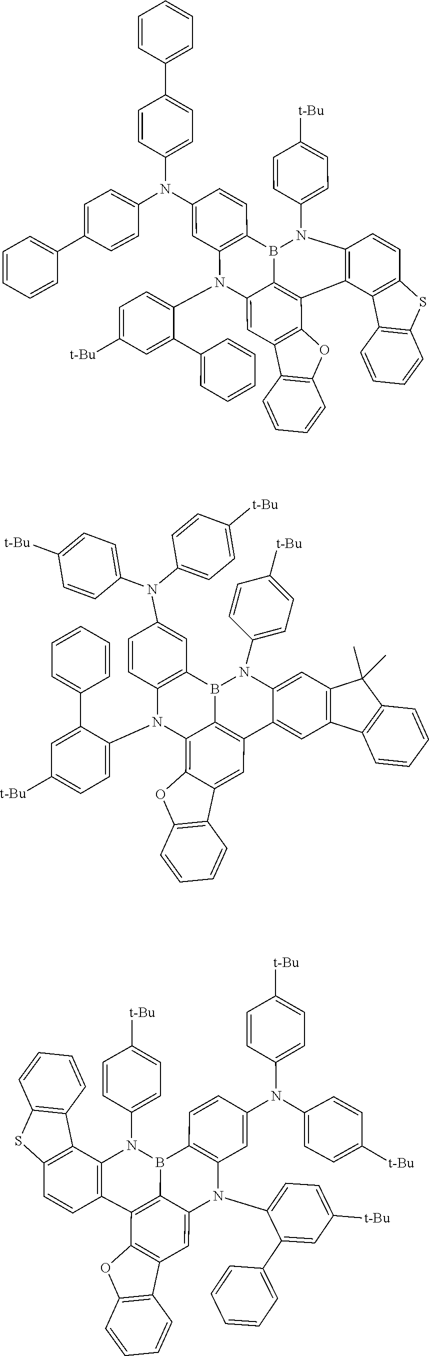 [SMILES: CC(C)(C)c1ccc(N2B3c4ccc(N(c5ccc(-c6ccccc6)cc5)c5ccc(-c6ccccc6)cc5)cc4N(c4ccc(C(C)(C)C)cc4-c4ccccc4)c4cc5c(oc6ccccc65)c(c43)-c3c2ccc2sc4ccccc4c32)cc1 ; CC(C)(C)c1ccc(N2B3c4cc(N(c5ccc(C(C)(C)C)cc5)c5ccc(C(C)(C)C)cc5)ccc4N(c4ccc(C(C)(C)C)cc4-c4ccccc4)c4c3c(cc3c4oc4ccccc43)-c3cc4c(cc32)C(C)(C)c2ccccc2-4)cc1 ; CC(C)(C)c1ccc(N2B3c4ccc(N(c5ccc(C(C)(C)C)cc5)c5ccc(C(C)(C)C)cc5)cc4N(c4ccc(C(C)(C)C)cc4-c4ccccc4)c4cc5c(oc6ccccc65)c(c43)-c3ccc4sc5ccccc5c4c32)cc1] 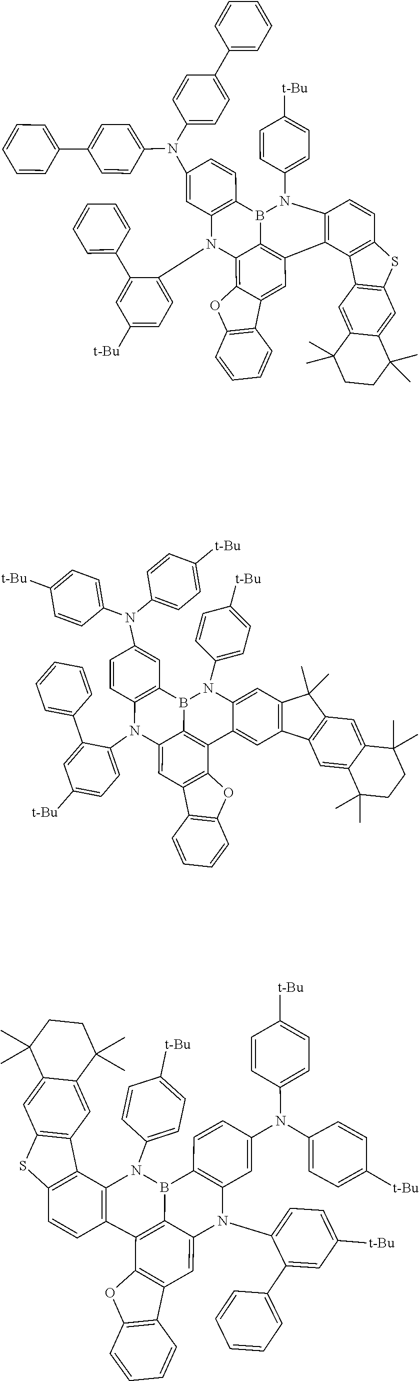 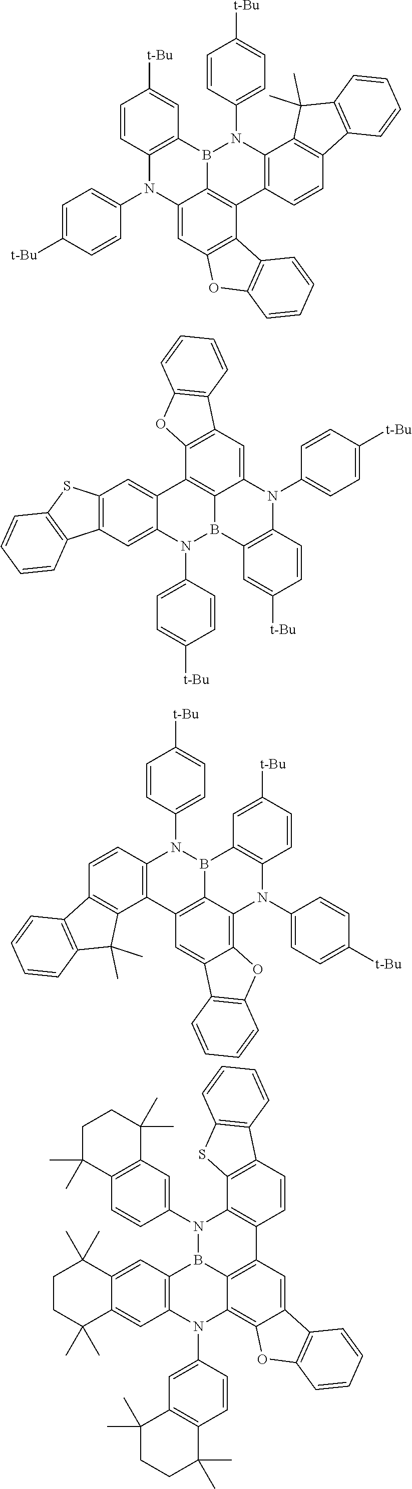 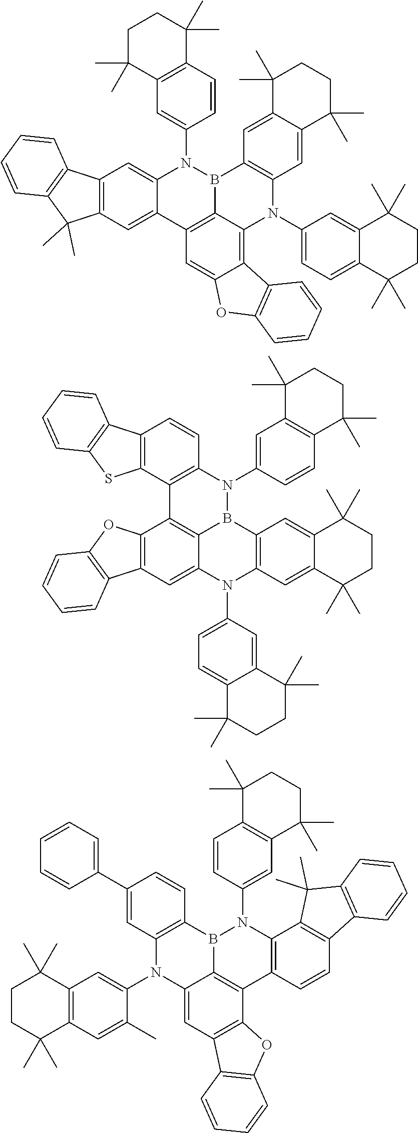 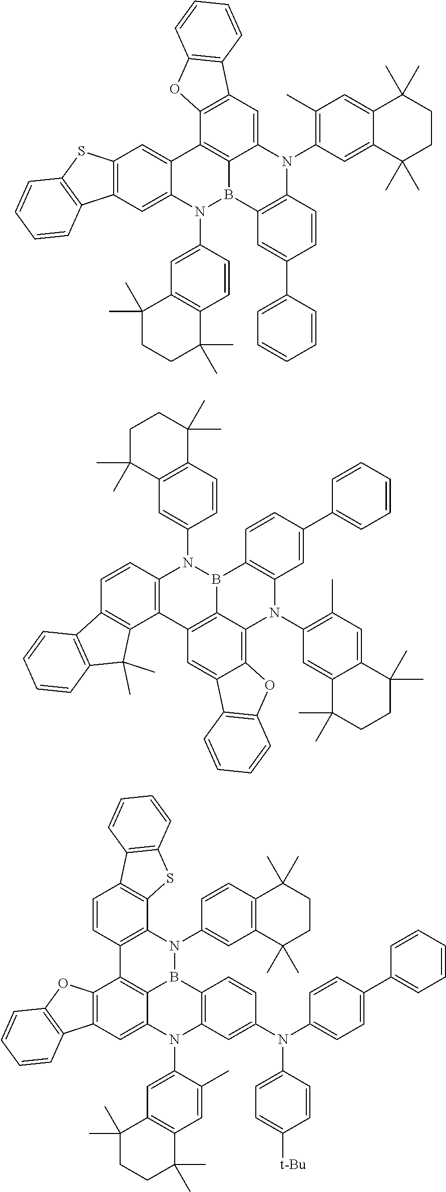 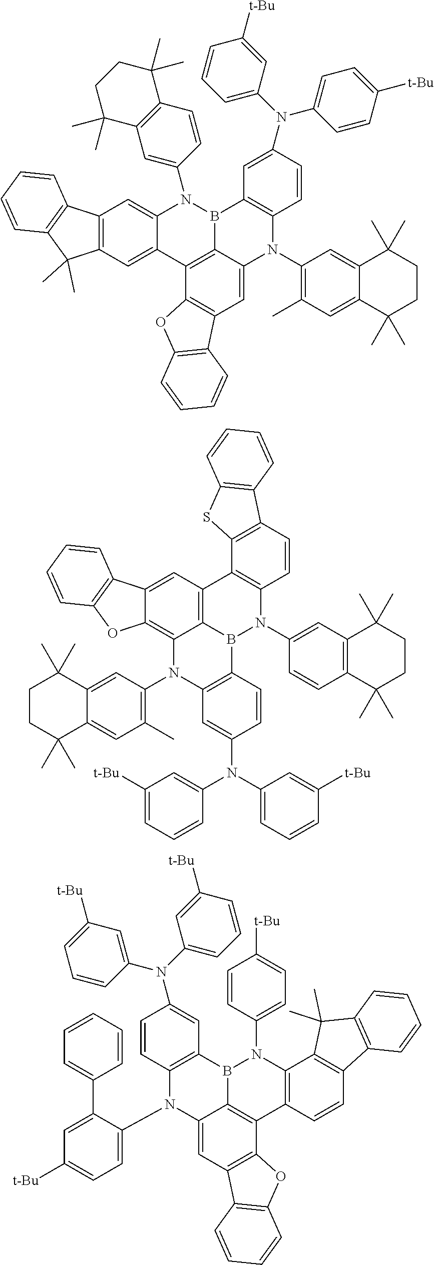 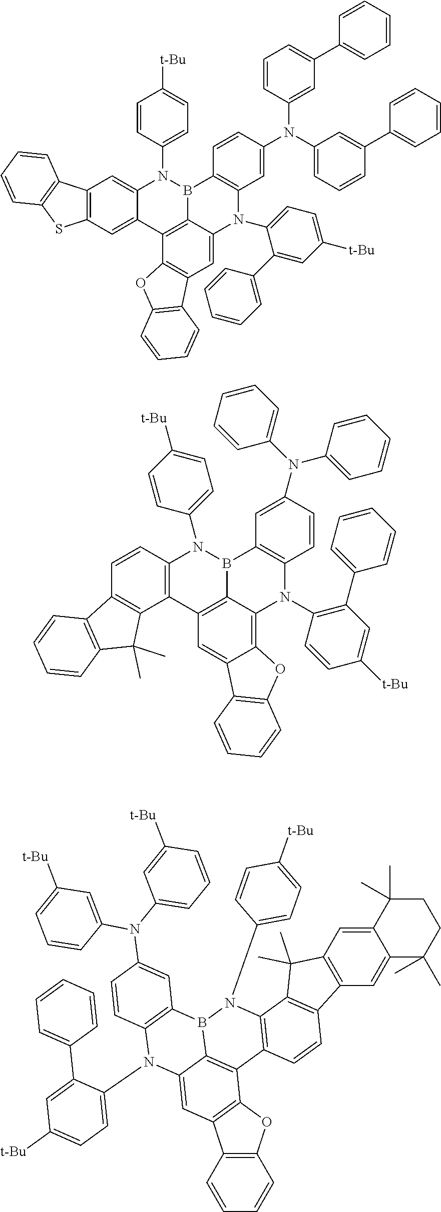 [SMILES: CC(C)(C)c1ccc(N2B3c4ccc(N(c5cccc(-c6ccccc6)c5)c5cccc(-c6ccccc6)c5)cc4N(c4ccc(C(C)(C)C)cc4-c4ccccc4)c4cc5c(oc6ccccc65)c(c43)-c3cc4sc5ccccc5c4cc32)cc1 ; CC(C)(C)c1ccc(N2B3c4cc(N(c5ccccc5)c5ccccc5)ccc4N(c4ccc(C(C)(C)C)cc4-c4ccccc4)c4c3c(cc3c4oc4ccccc43)-c3c2ccc2c3C(C)(C)c3ccccc3-2)cc1 ; CC(C)(C)c1ccc(N2B3c4cc(N(c5cccc(C(C)(C)C)c5)c5cccc(C(C)(C)C)c5)ccc4N(c4ccc(C(C)(C)C)cc4-c4ccccc4)c4cc5c(oc6ccccc65)c(c43)-c3ccc4c(c32)C(C)(C)c2cc3c(cc2-4)C(C)(C)CCC3(C)C)cc1] 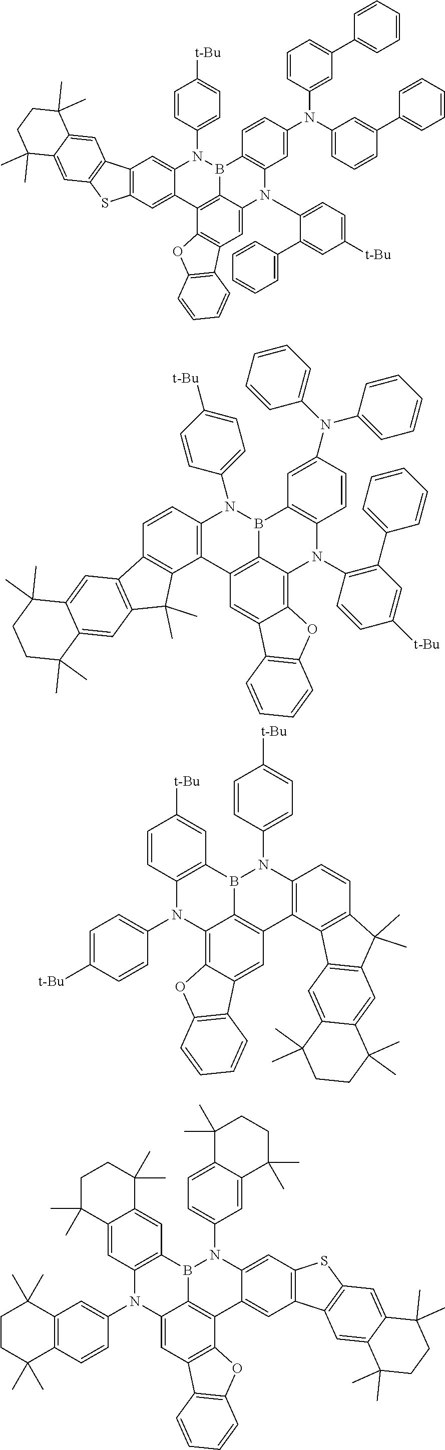 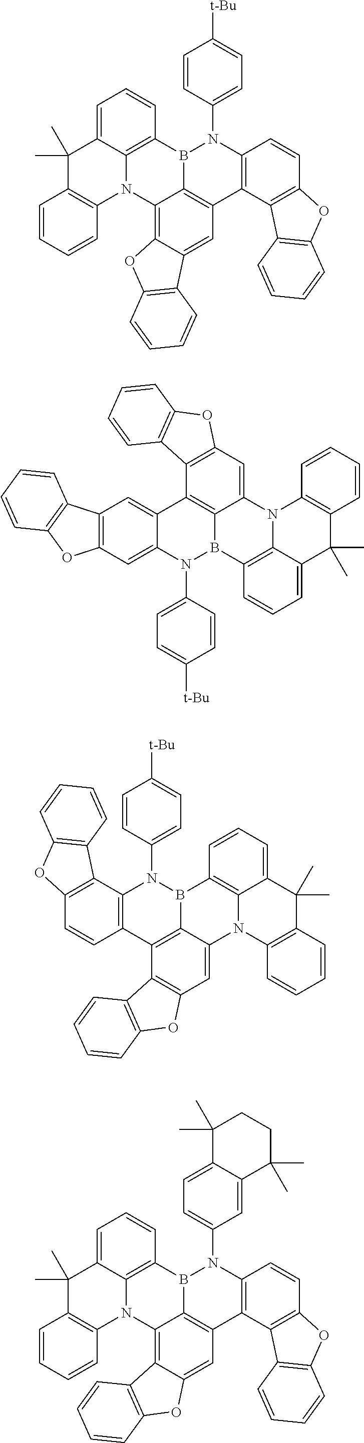 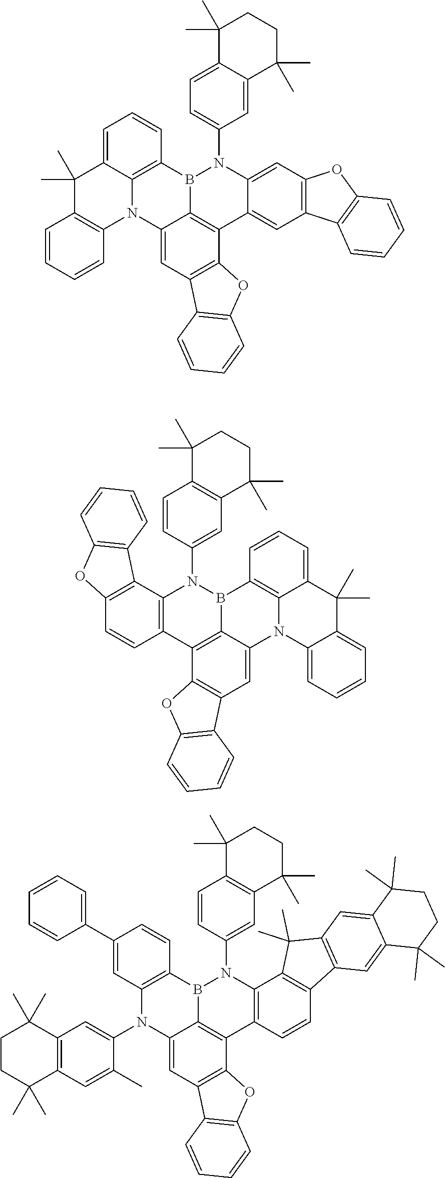 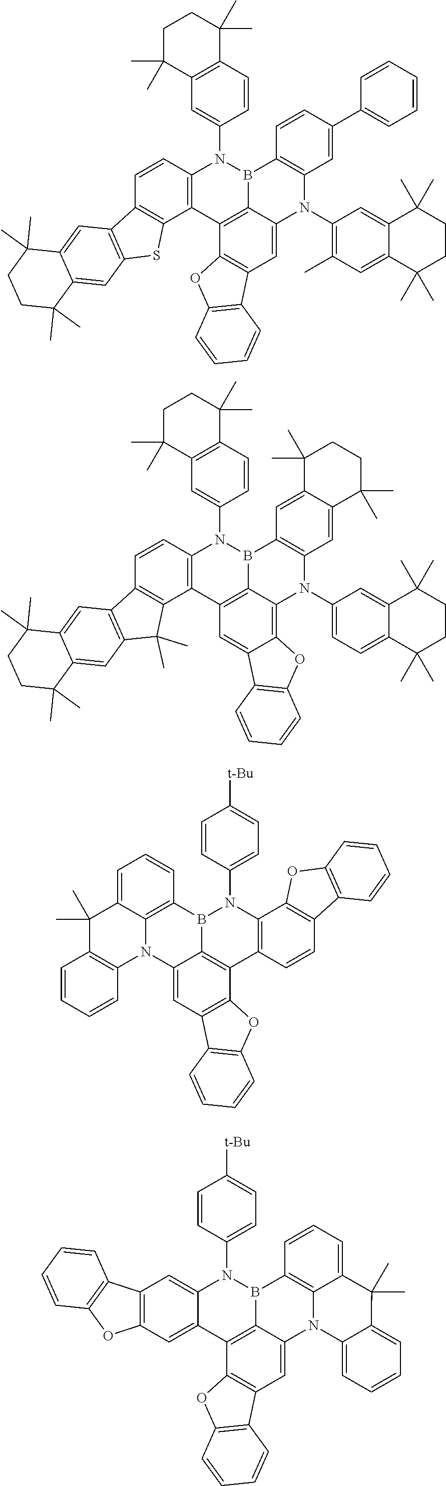 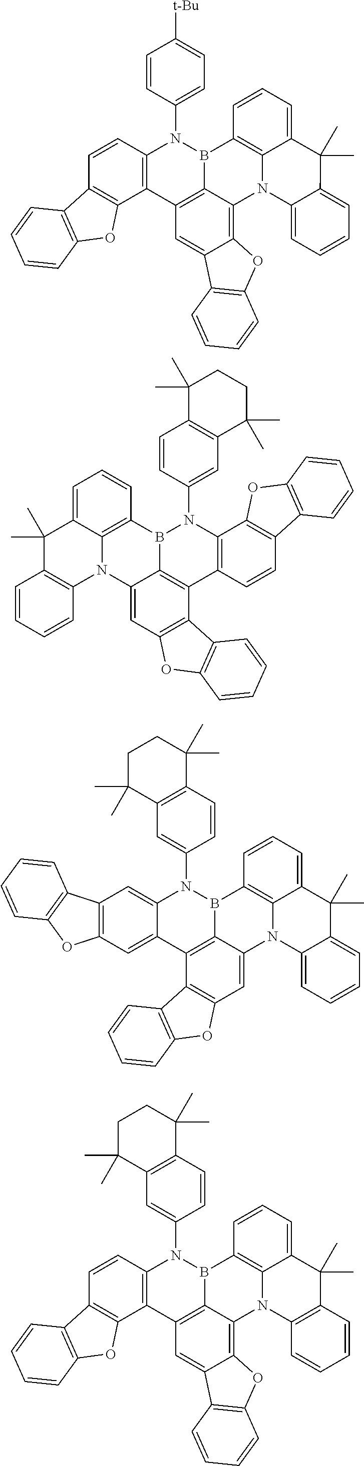 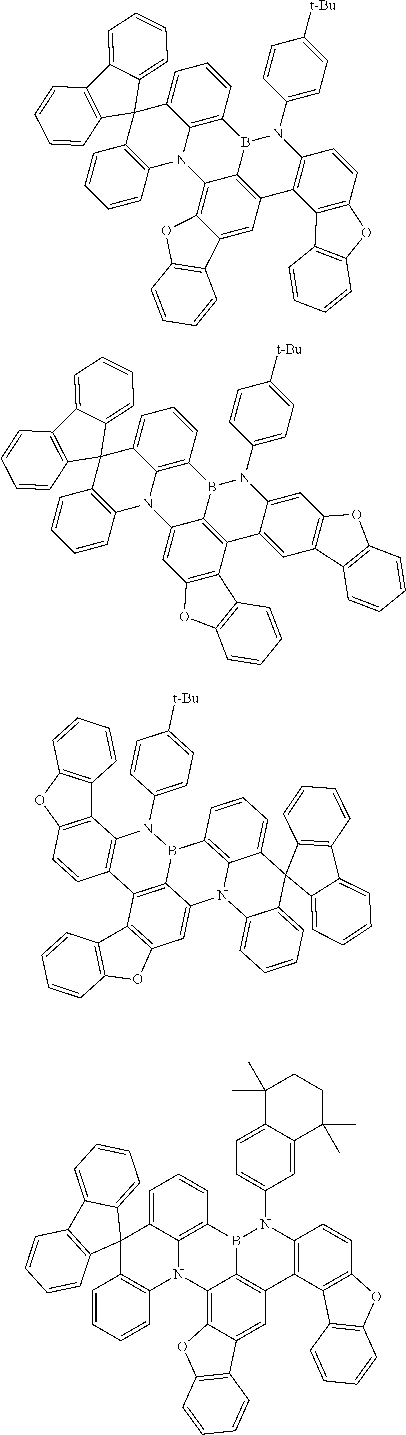 [SMILES: CC(C)(C)c1ccc(N2B3c4cccc5c4N(c4ccccc4C54c5ccccc5-c5ccccc54)c4c3c(cc3c4oc4ccccc43)-c3c2ccc2oc4ccccc4c32)cc1 ; CC(C)(C)c1ccc(N2B3c4cccc5c4N(c4ccccc4C54c5ccccc5-c5ccccc54)c4cc5oc6ccccc6c5c(c43)-c3cc4c(cc32)oc2ccccc24)cc1 ; CC(C)(C)c1ccc(N2B3c4cccc5c4N(c4ccccc4C54c5ccccc5-c5ccccc54)c4cc5oc6ccccc6c5c(c43)-c3ccc4oc5ccccc5c4c32)cc1 ; CC1(C)CCC(C)(C)c2cc(N3B4c5cccc6c5N(c5ccccc5C65c6ccccc6-c6ccccc65)c5c4c(cc4c5oc5ccccc54)-c4c3ccc3oc5ccccc5c43)ccc21] 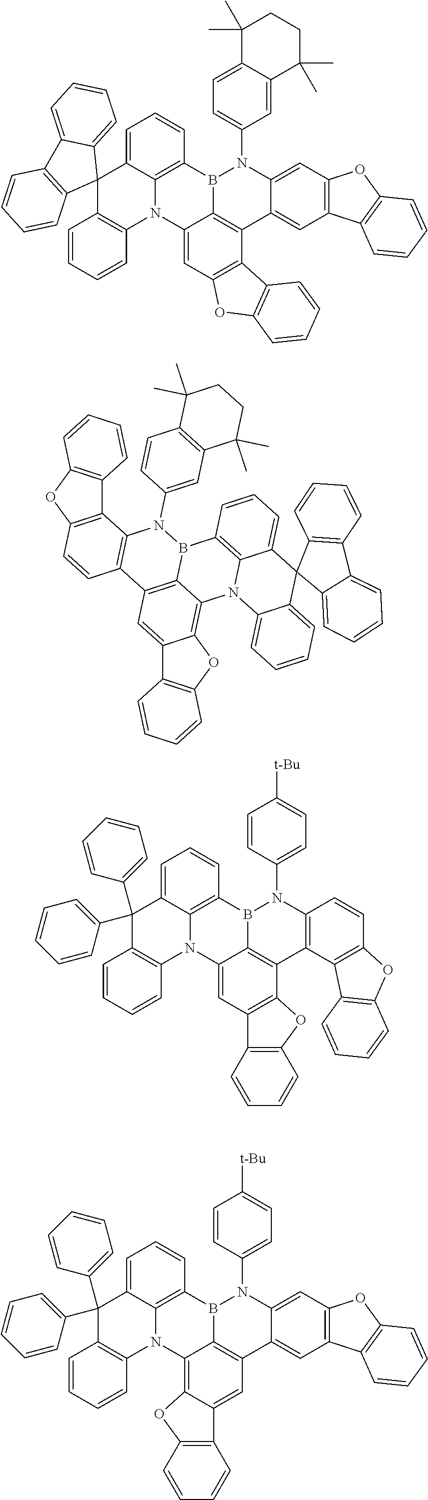 [SMILES: CC1(C)CCC(C)(C)c2cc(N3B4c5cccc6c5N(c5ccccc5C65c6ccccc6-c6ccccc65)c5cc6oc7ccccc7c6c(c54)-c4cc5c(cc43)oc3ccccc35)ccc21 ; CC1(C)CCC(C)(C)c2cc(N3B4c5cccc6c5N(c5ccccc5C65c6ccccc6-c6ccccc65)c5c4c(cc4c5oc5ccccc54)-c4ccc5oc6ccccc6c5c43)ccc21 ; CC(C)(C)c1ccc(N2B3c4cccc5c4N(c4ccccc4C5(c4ccccc4)c4ccccc4)c4cc5c(oc6ccccc65)c(c43)-c3c2ccc2oc4ccccc4c32)cc1 ; CC(C)(C)c1ccc(N2B3c4cccc5c4N(c4ccccc4C5(c4ccccc4)c4ccccc4)c4c3c(cc3c4oc4ccccc43)-c3cc4c(cc32)oc2ccccc24)cc1] 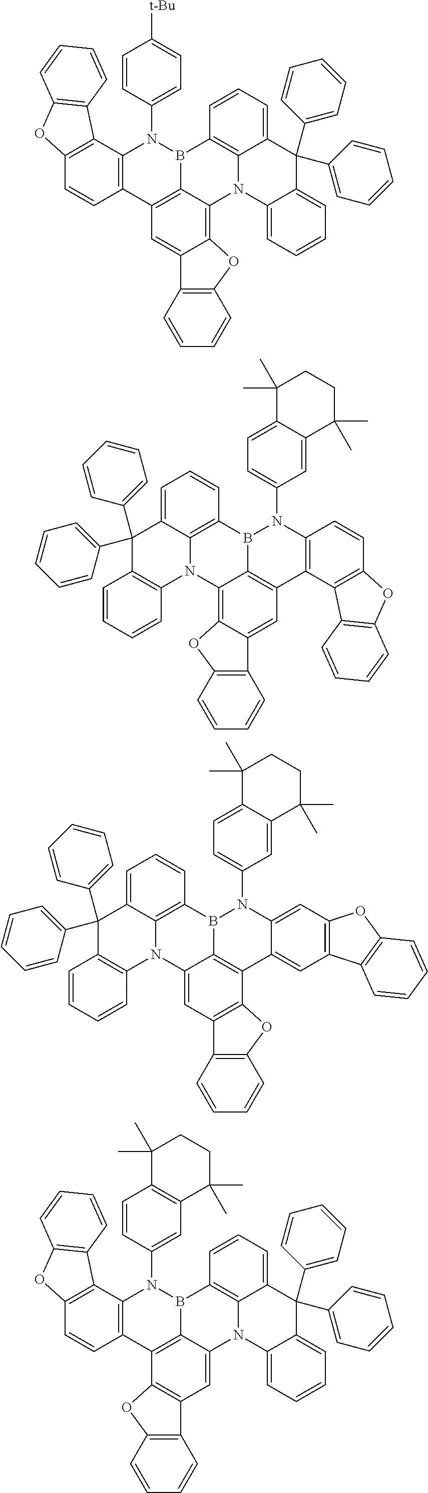 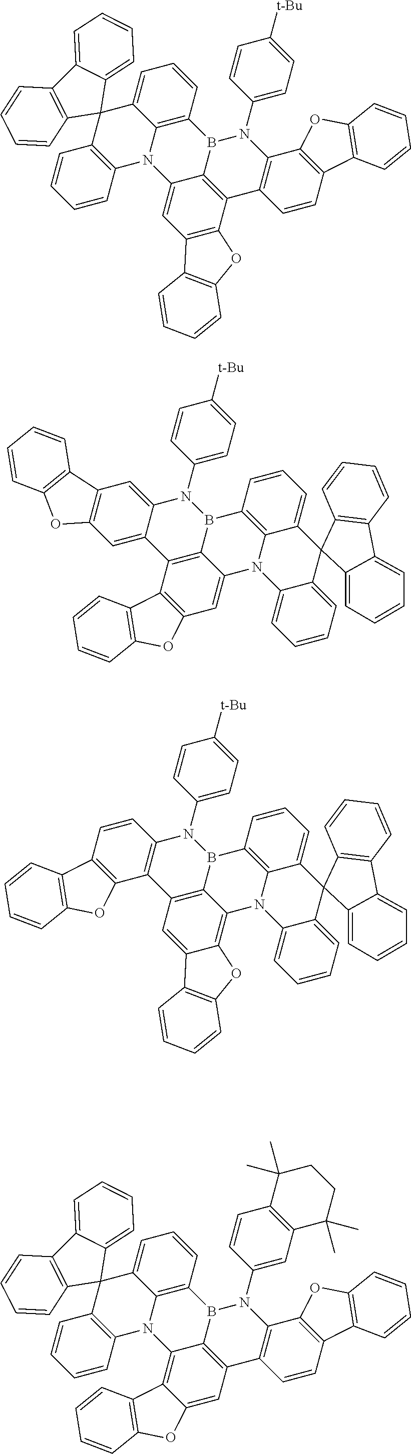 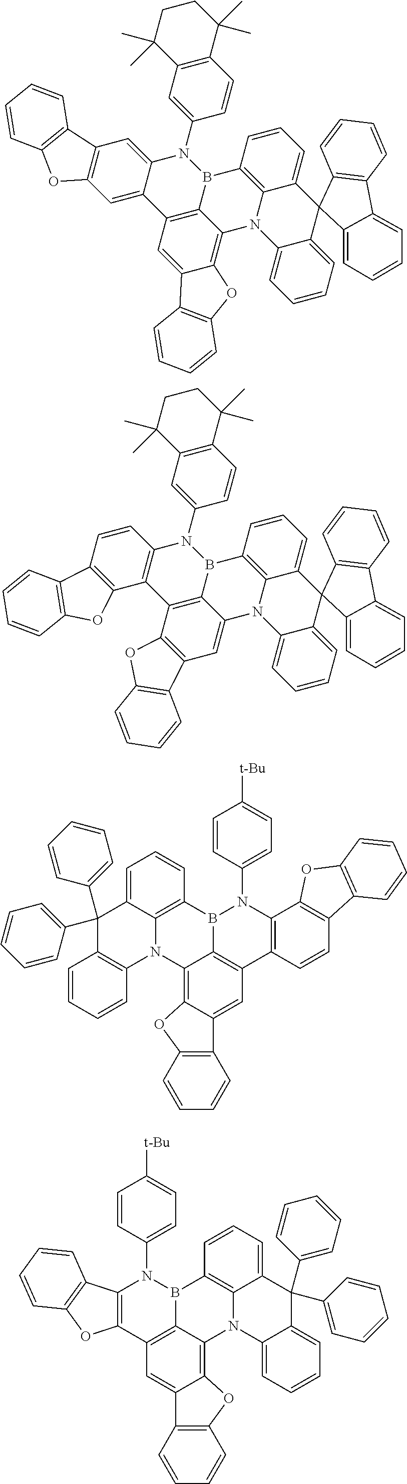 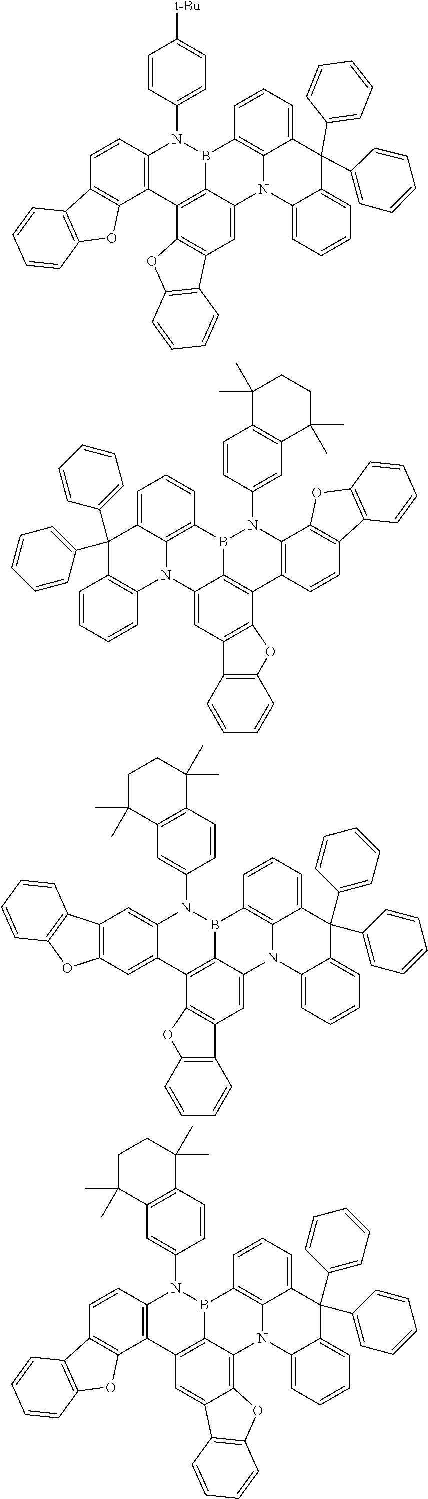 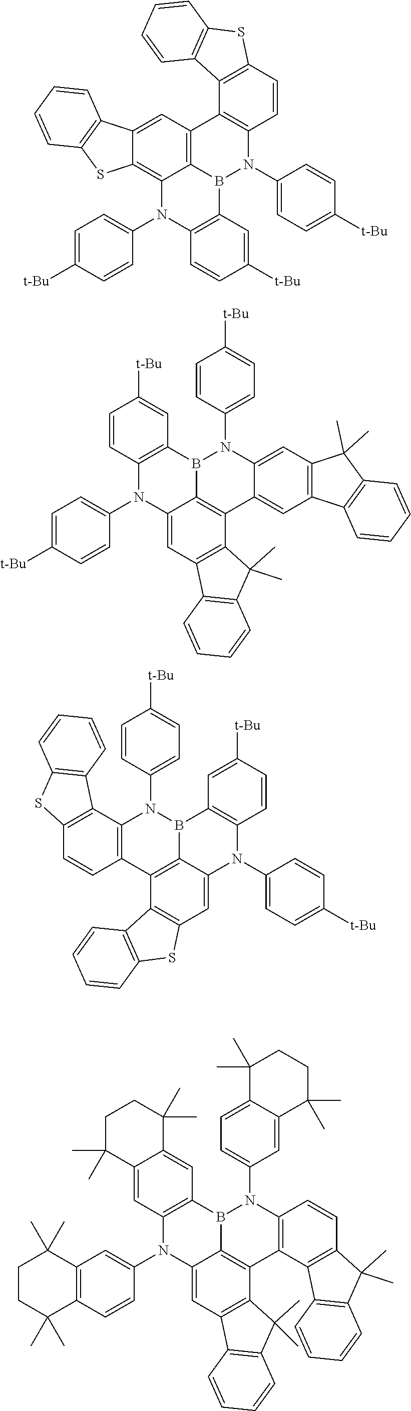 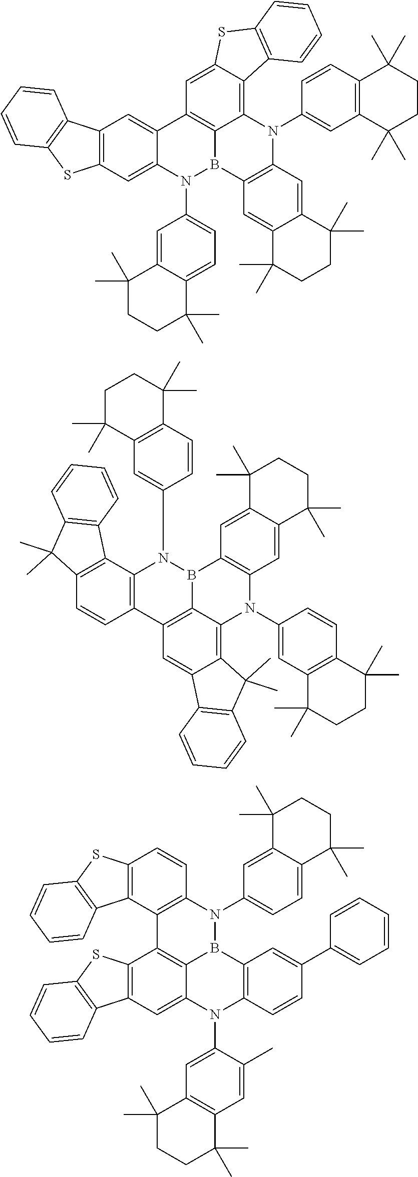 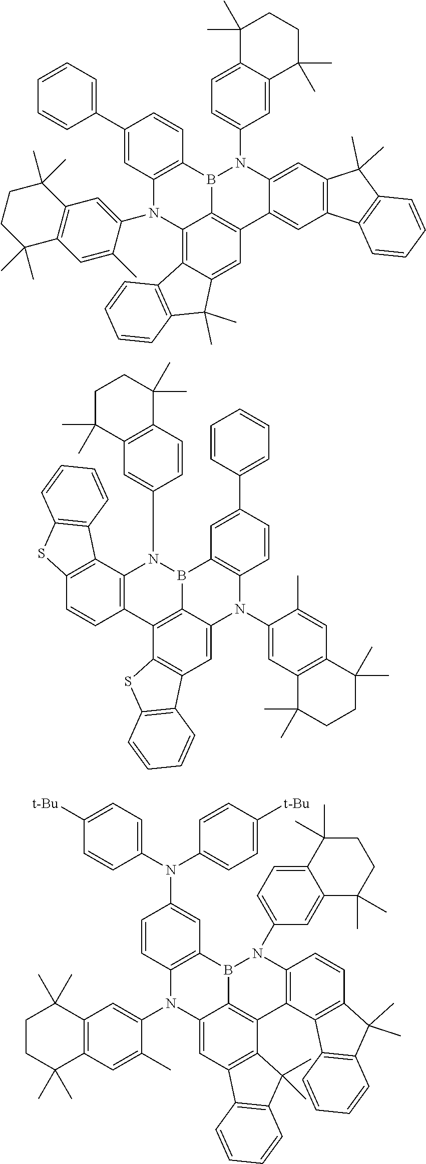 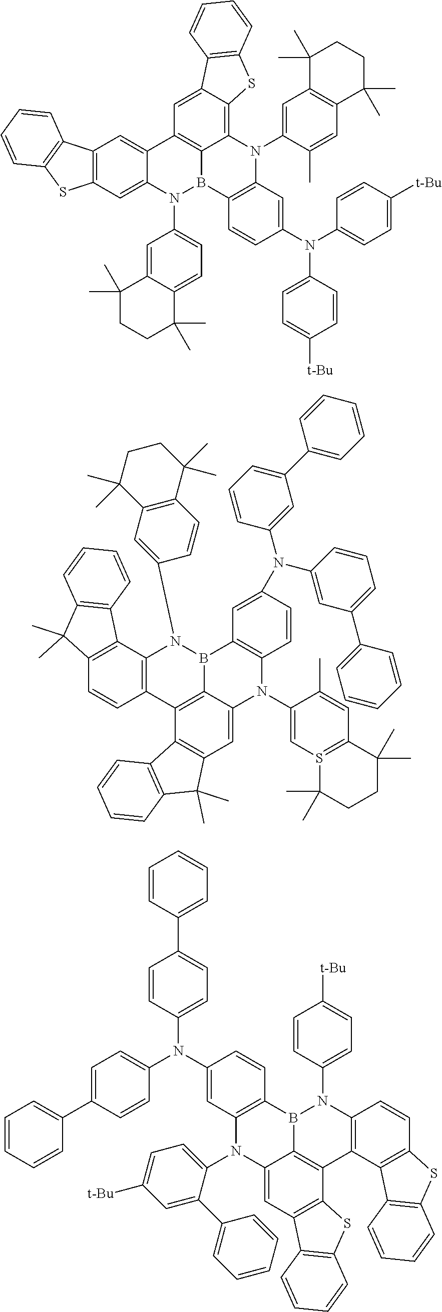 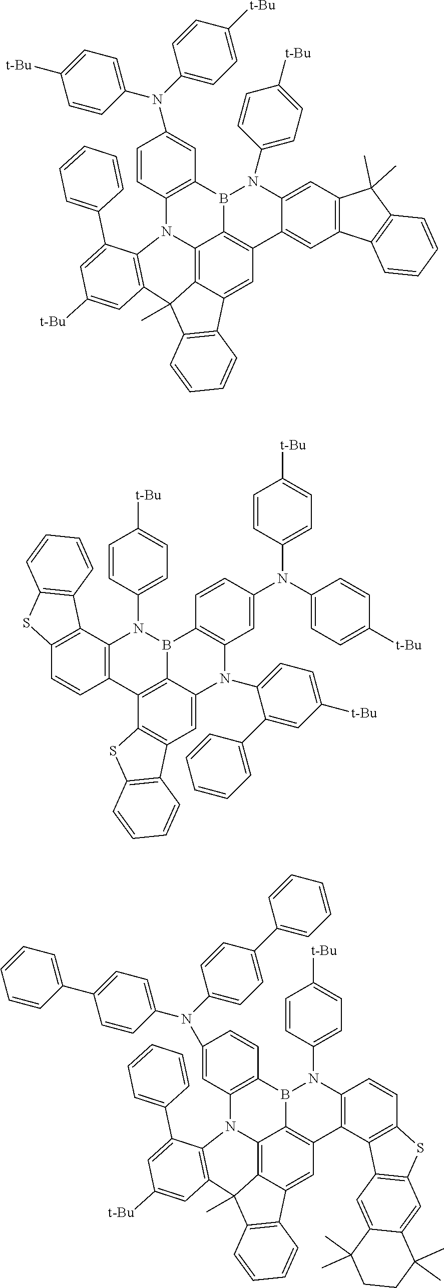 [SMILES: CC(C)(C)c1ccc(N2B3c4cc(N(c5ccc(C(C)(C)C)cc5)c5ccc(C(C)(C)C)cc5)ccc4N4c5c(-c6ccccc6)cc(C(C)(C)C)cc5C5(C)c6ccccc6-c6cc(c3c4c65)-c3cc4c(cc32)C(C)(C)c2ccccc2-4)cc1 ; CC(C)(C)c1ccc(N2B3c4ccc(N(c5ccc(C(C)(C)C)cc5)c5ccc(C(C)(C)C)cc5)cc4N(c4ccc(C(C)(C)C)cc4-c4ccccc4)c4cc5c(sc6ccccc65)c(c43)-c3ccc4sc5ccccc5c4c32)cc1 ; CC(C)(C)c1ccc(N2B3c4ccc(N(c5ccc(-c6ccccc6)cc5)c5ccc(-c6ccccc6)cc5)cc4N4c5c(-c6ccccc6)cc(C(C)(C)C)cc5C5(C)c6ccccc6-c6cc(c3c4c65)-c3c2ccc2sc4cc5c(cc4c32)C(C)(C)CCC5(C)C)cc1] 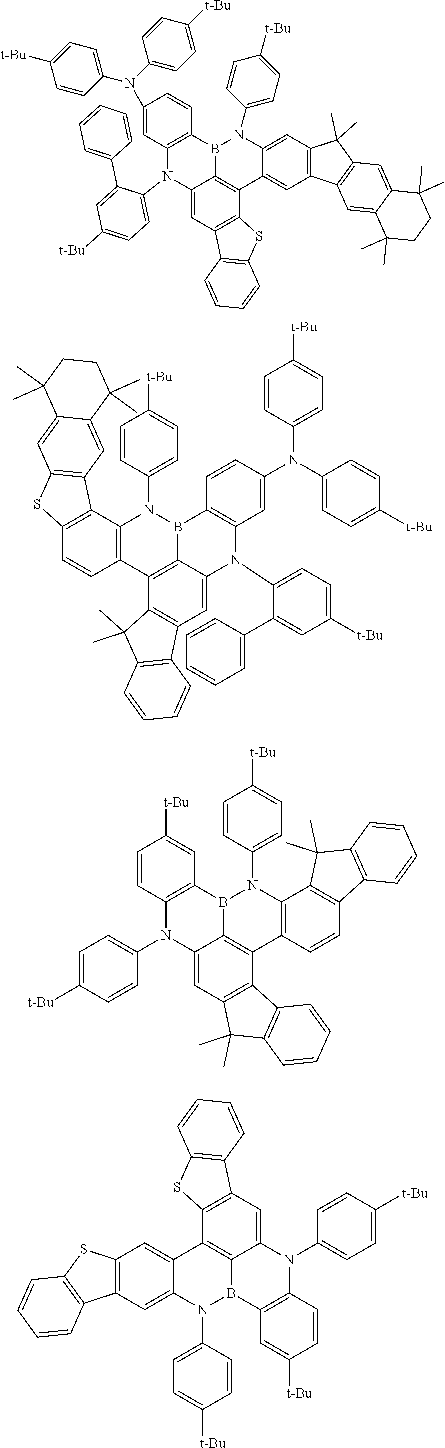 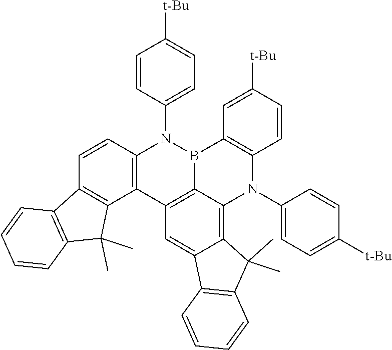 [SMILES: CC(C)(C)c1ccc(N2B3c4cc(C(C)(C)C)ccc4N(c4ccc(C(C)(C)C)cc4)c4c3c(cc3c4C(C)(C)c4ccccc4-3)-c3c2ccc2c3C(C)(C)c3ccccc3-2)cc1] 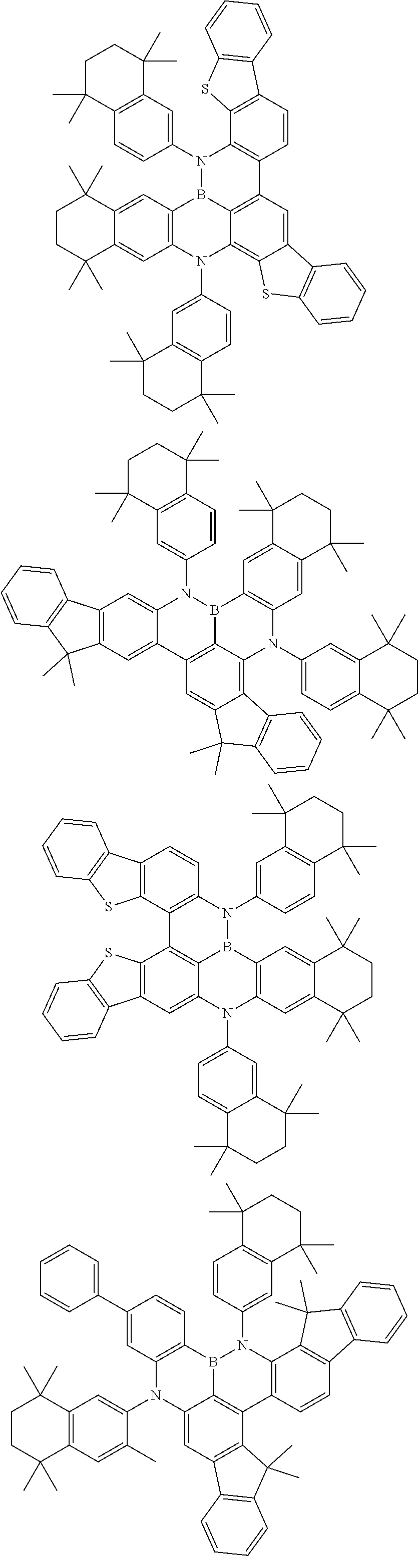 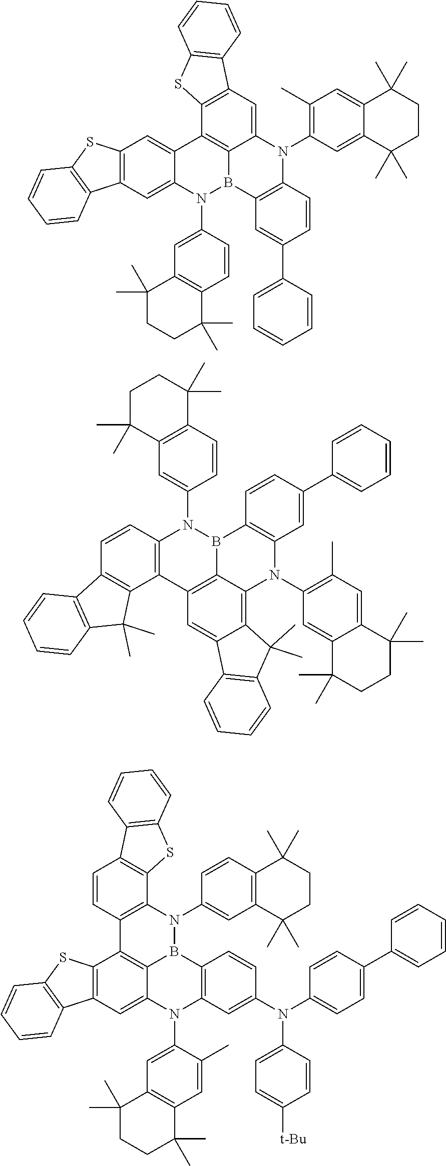 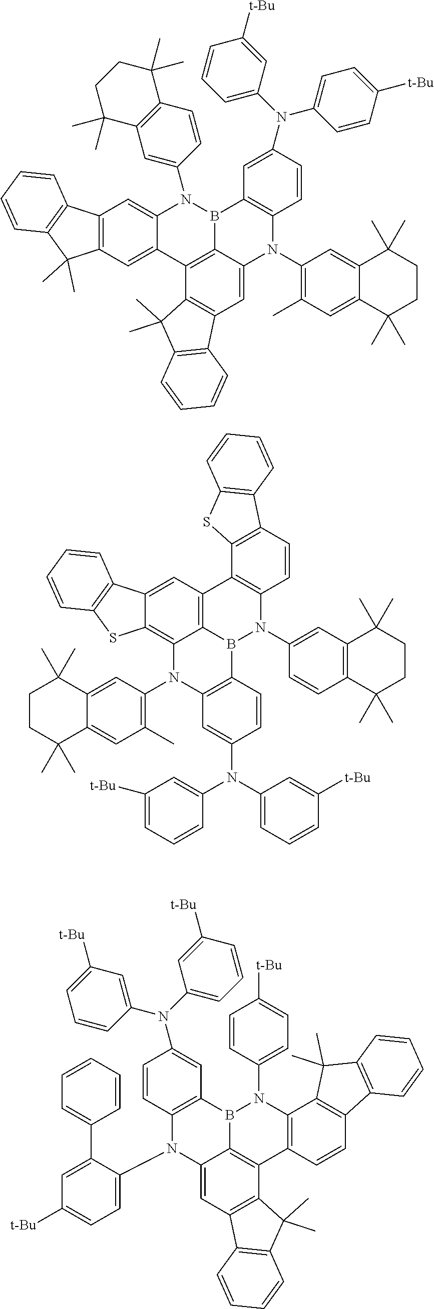 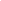 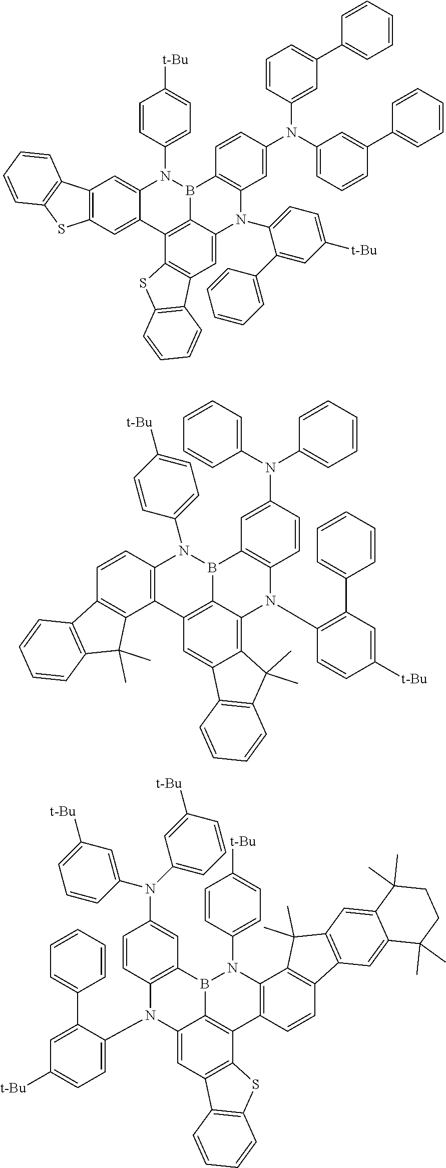 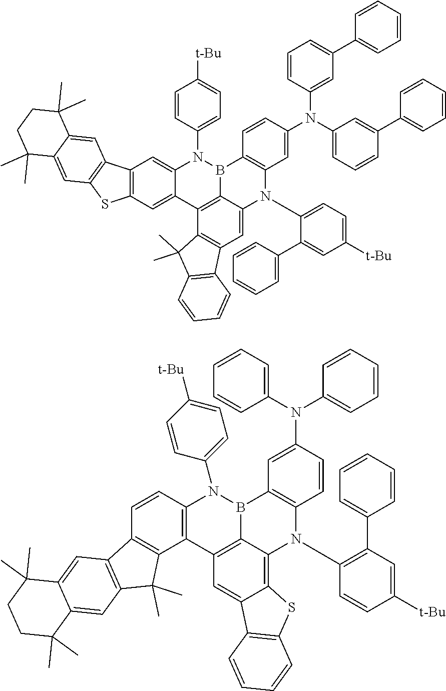 [SMILES: CC(C)(C)c1ccc(N2B3c4ccc(N(c5cccc(-c6ccccc6)c5)c5cccc(-c6ccccc6)c5)cc4N(c4ccc(C(C)(C)C)cc4-c4ccccc4)c4cc5c(c(c43)-c3cc4sc6cc7c(cc6c4cc32)C(C)(C)CCC7(C)C)C(C)(C)c2ccccc2-5)cc1 ; CC(C)(C)c1ccc(N2B3c4cc(N(c5ccccc5)c5ccccc5)ccc4N(c4ccc(C(C)(C)C)cc4-c4ccccc4)c4c3c(cc3c4sc4ccccc43)-c3c2ccc2c3C(C)(C)c3cc4c(cc3-2)C(C)(C)CCC4(C)C)cc1] 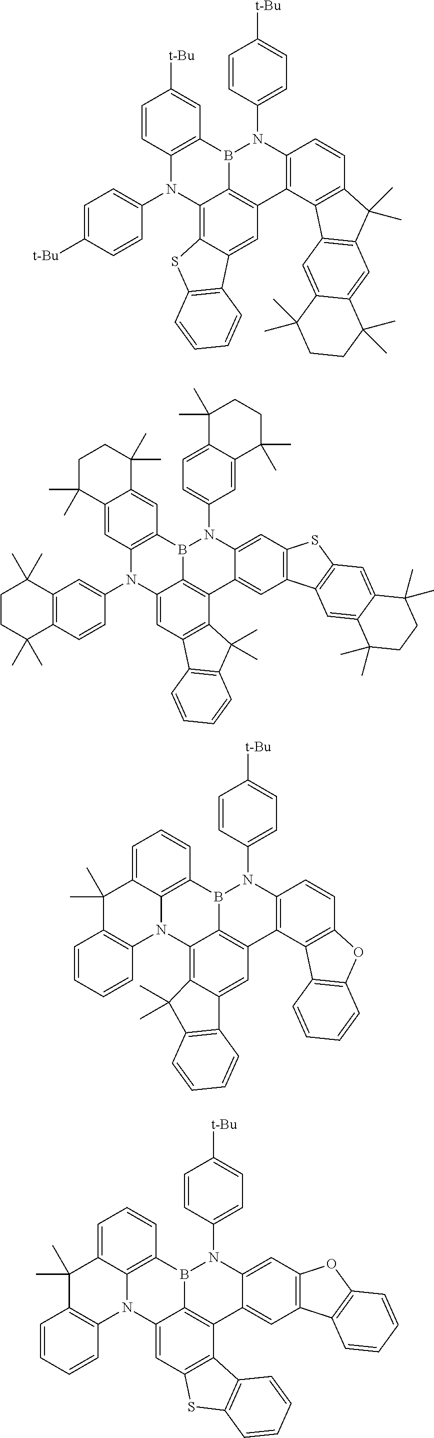 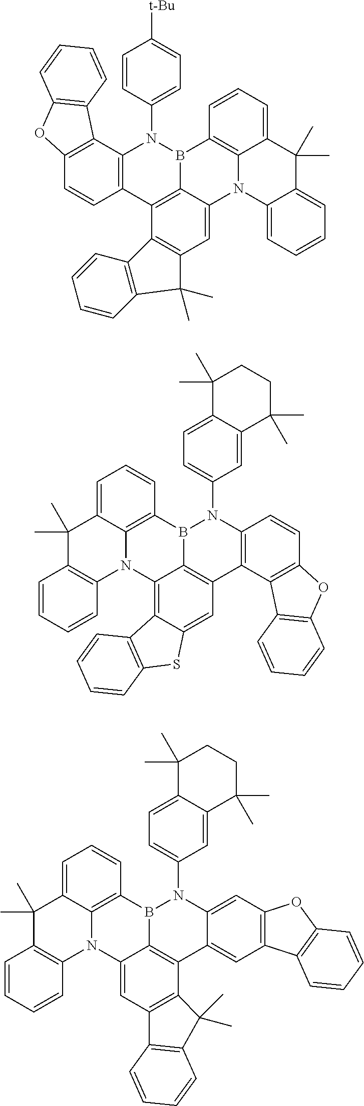 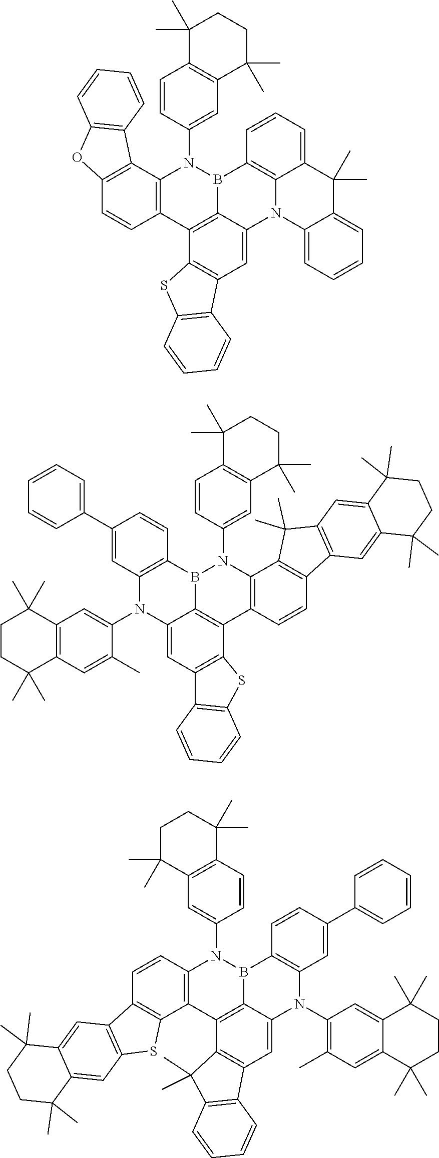 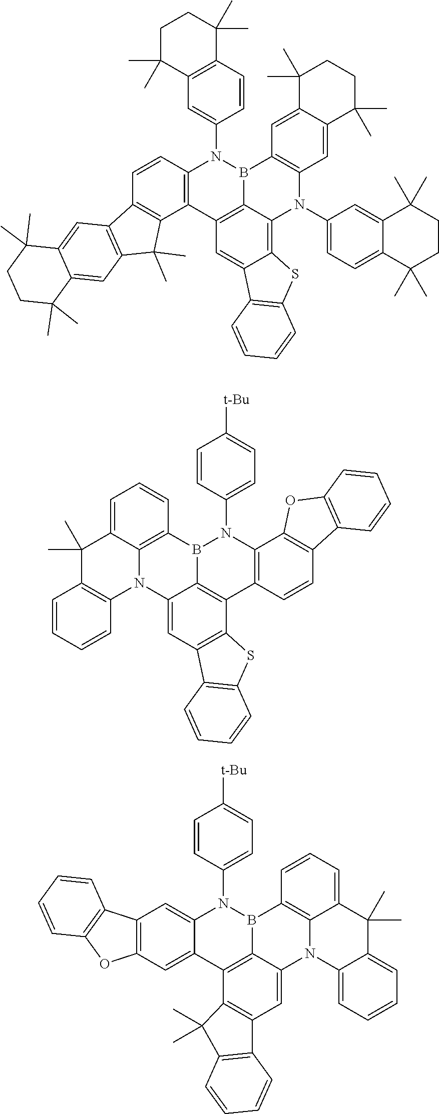 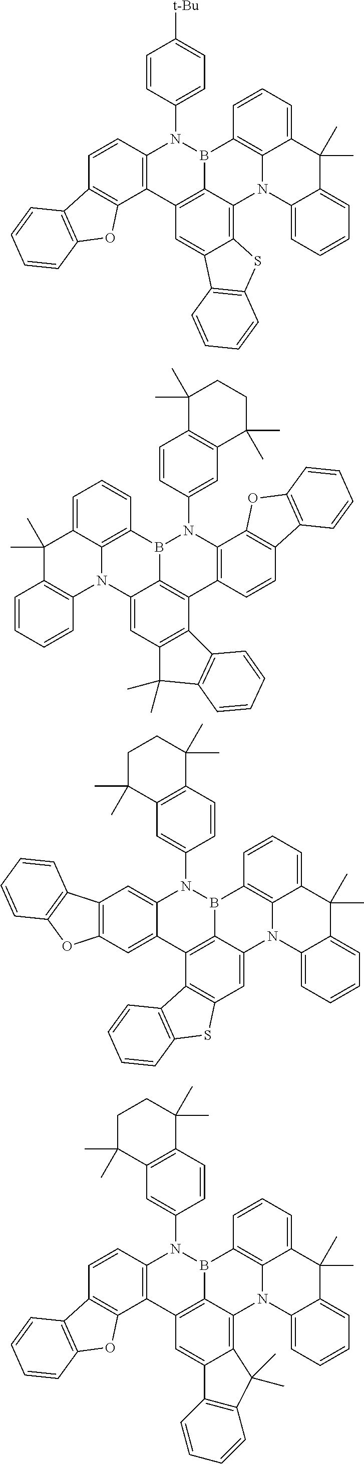 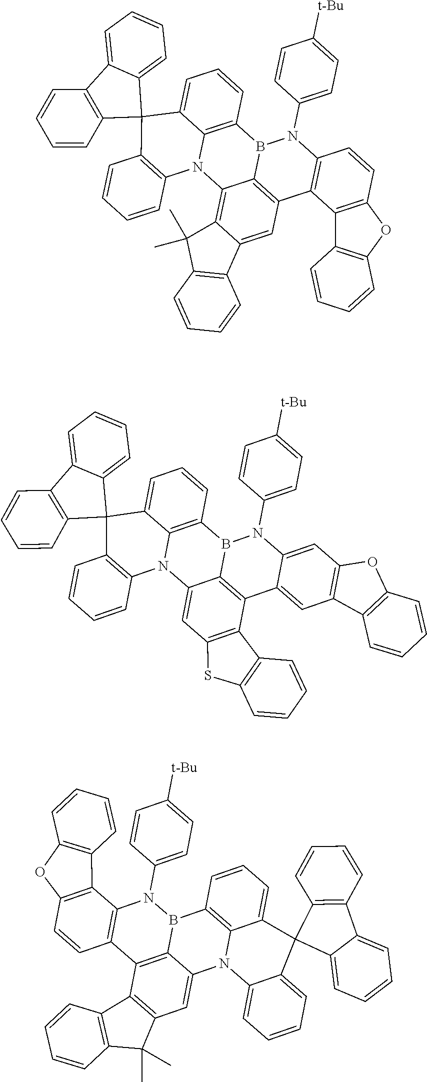 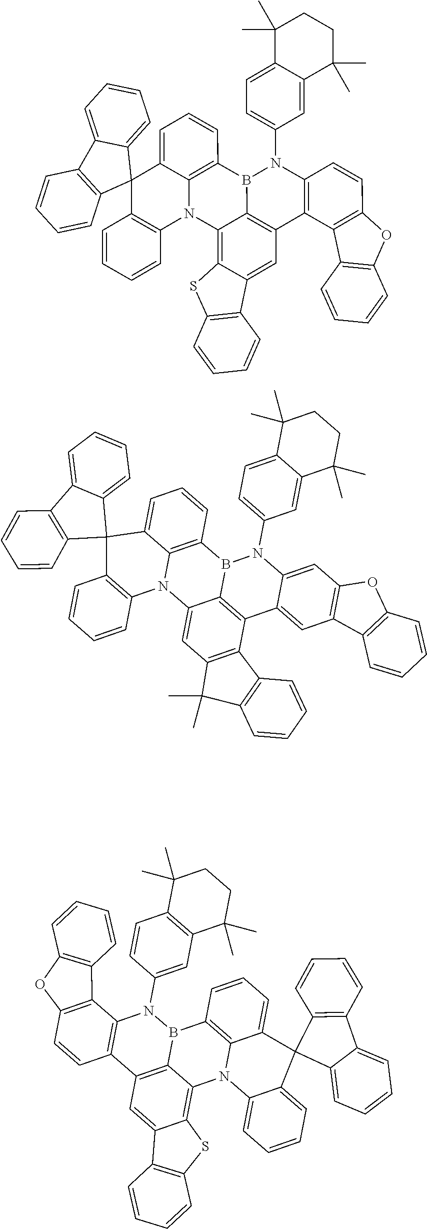 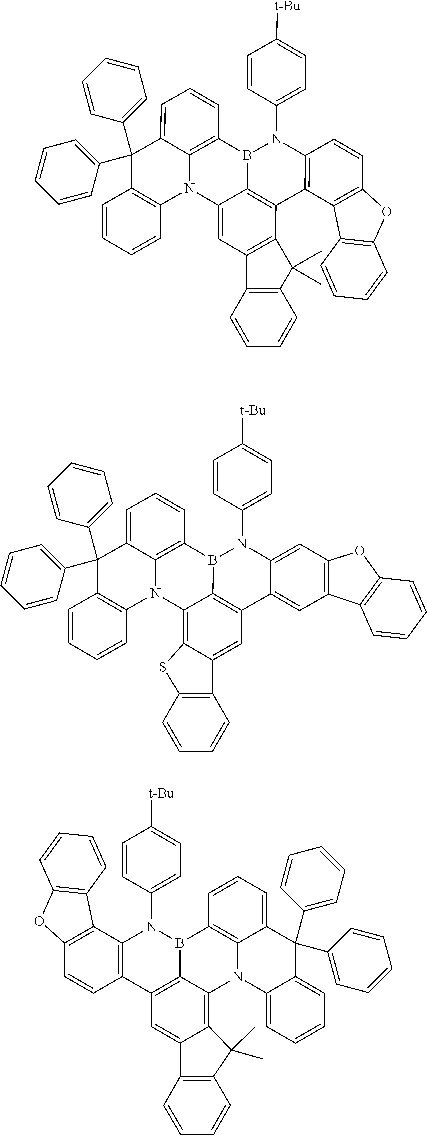 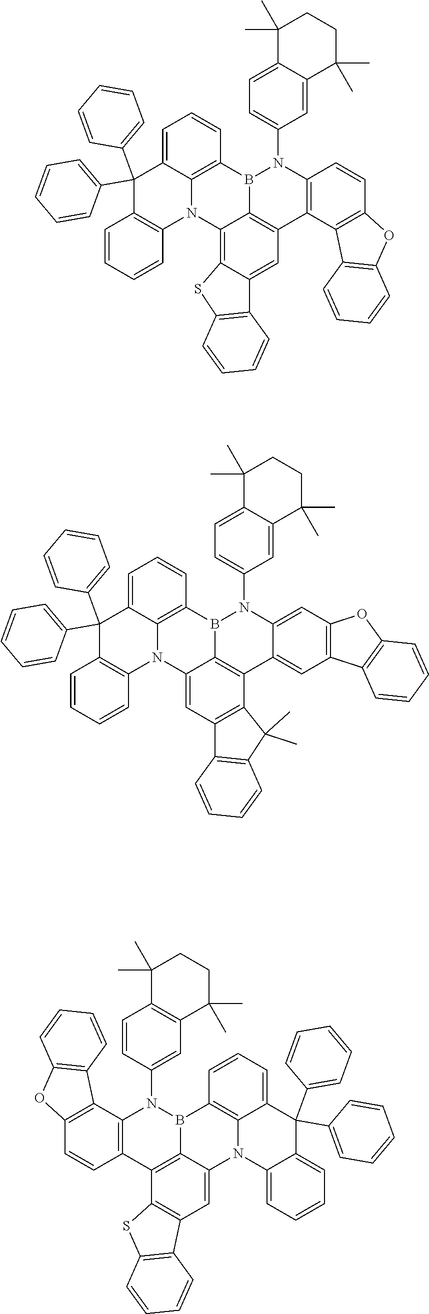 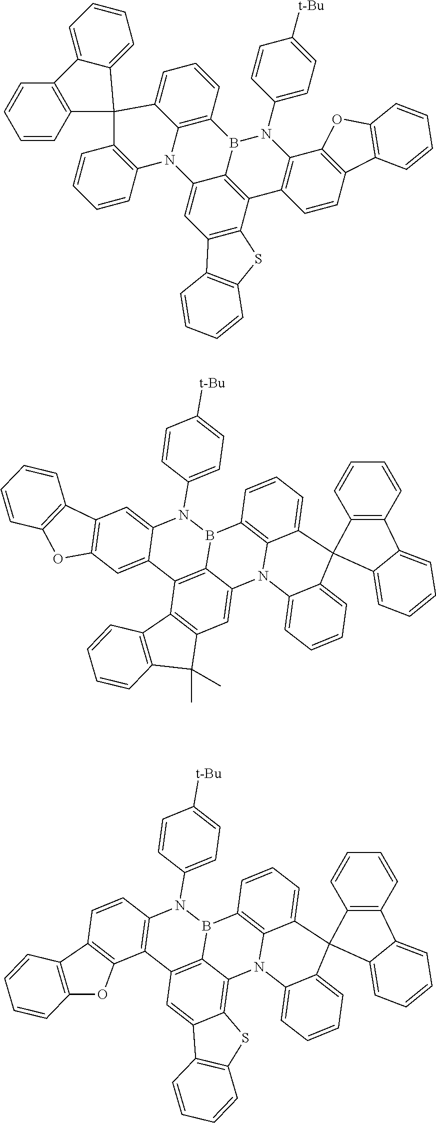 [SMILES: CC(C)(C)c1ccc(N2B3c4cccc5c4N(c4ccccc4C54c5ccccc5-c5ccccc54)c4cc5c(sc6ccccc65)c(c43)-c3ccc4c(oc5ccccc54)c32)cc1 ; CC(C)(C)c1ccc(N2B3c4cccc5c4N(c4ccccc4C54c5ccccc5-c5ccccc54)c4cc5c(c(c43)-c3cc4oc6ccccc6c4cc32)-c2ccccc2C5(C)C)cc1 ; CC(C)(C)c1ccc(N2B3c4cccc5c4N(c4ccccc4C54c5ccccc5-c5ccccc54)c4c3c(cc3c4sc4ccccc43)-c3c2ccc2c3oc3ccccc32)cc1] 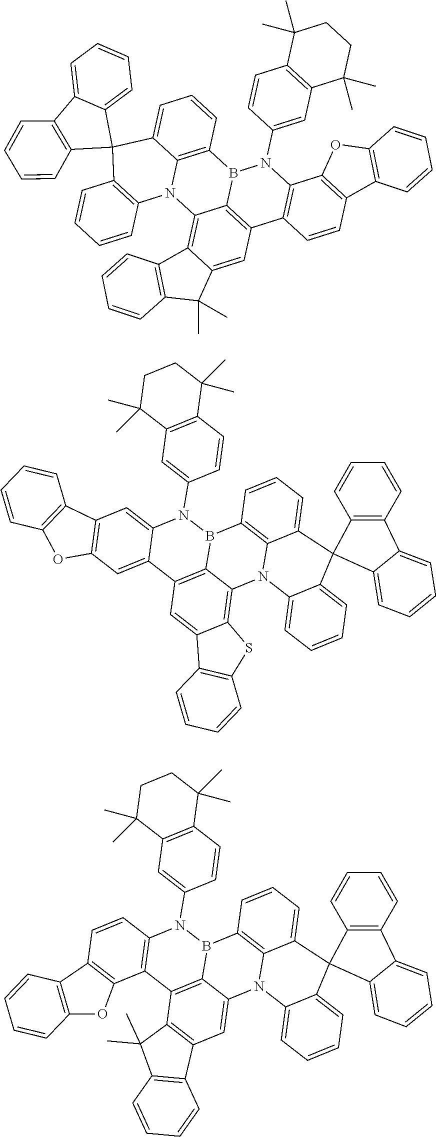 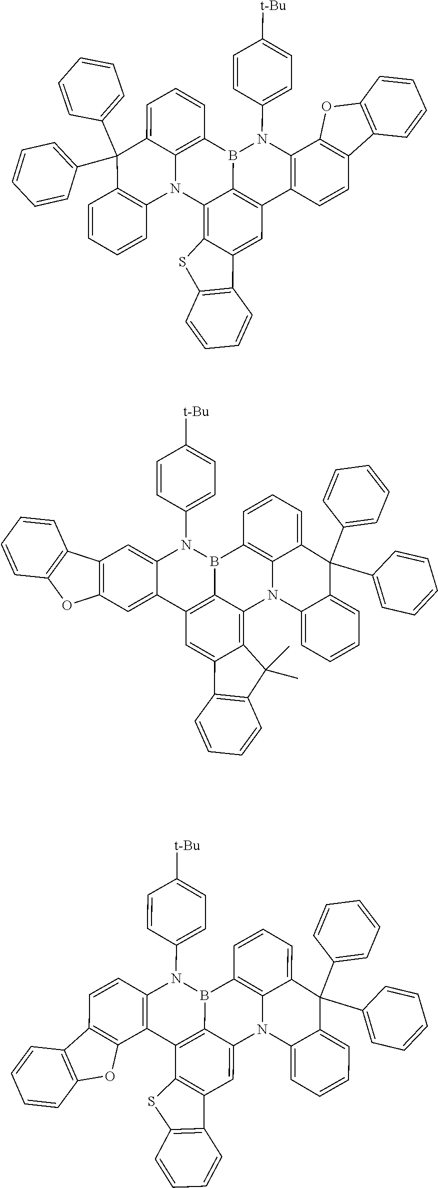 [SMILES: CC(C)(C)c1ccc(N2B3c4cccc5c4N(c4ccccc4C5(c4ccccc4)c4ccccc4)c4c3c(cc3c4sc4ccccc43)-c3ccc4c(oc5ccccc54)c32)cc1 ; CC(C)(C)c1ccc(N2B3c4cccc5c4N(c4ccccc4C5(c4ccccc4)c4ccccc4)c4c3c(cc3c4C(C)(C)c4ccccc4-3)-c3cc4oc5ccccc5c4cc32)cc1 ; CC(C)(C)c1ccc(N2B3c4cccc5c4N(c4ccccc4C5(c4ccccc4)c4ccccc4)c4cc5c(sc6ccccc65)c(c43)-c3c2ccc2c3oc3ccccc32)cc1] 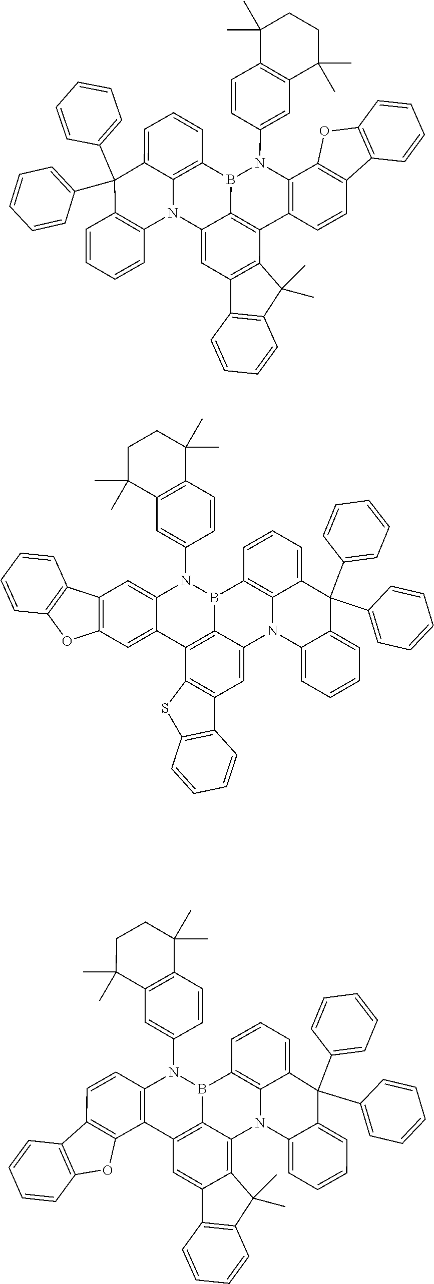 [SMILES: CC1(C)CCC(C)(C)c2cc(N3B4c5cccc6c5N(c5ccccc5C6(c5ccccc5)c5ccccc5)c5cc6c(c(c54)-c4ccc5c(oc7ccccc75)c43)C(C)(C)c3ccccc3-6)ccc21 ; CC1(C)CCC(C)(C)c2cc(N3B4c5cccc6c5N(c5ccccc5C6(c5ccccc5)c5ccccc5)c5cc6c(sc7ccccc76)c(c54)-c4cc5oc6ccccc6c5cc43)ccc21 ; CC1(C)CCC(C)(C)c2cc(N3B4c5cccc6c5N(c5ccccc5C6(c5ccccc5)c5ccccc5)c5c4c(cc4c5C(C)(C)c5ccccc5-4)-c4c3ccc3c4oc4ccccc43)ccc21] 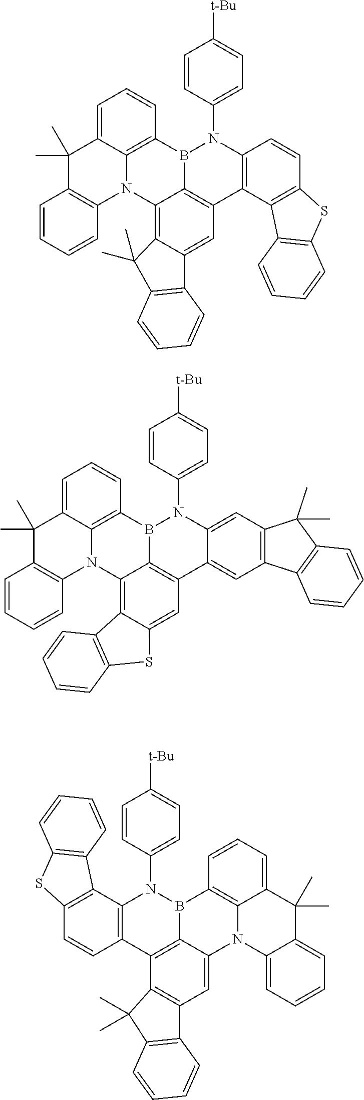 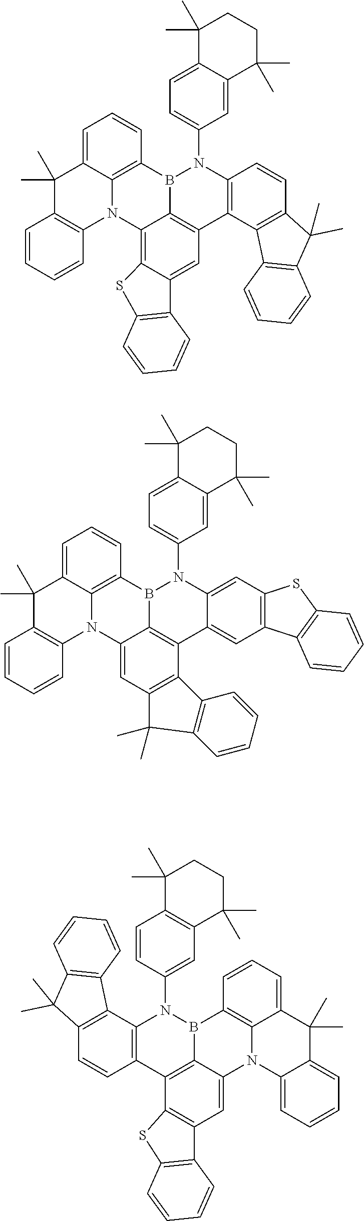 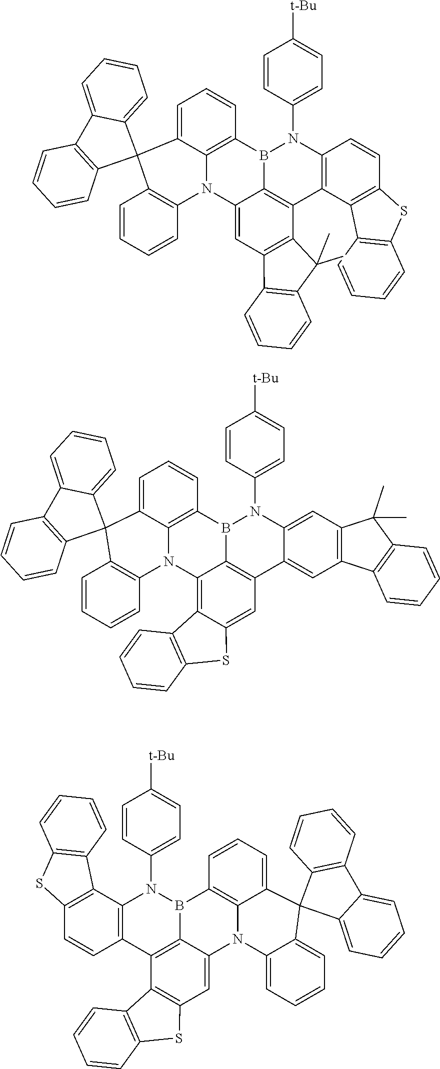 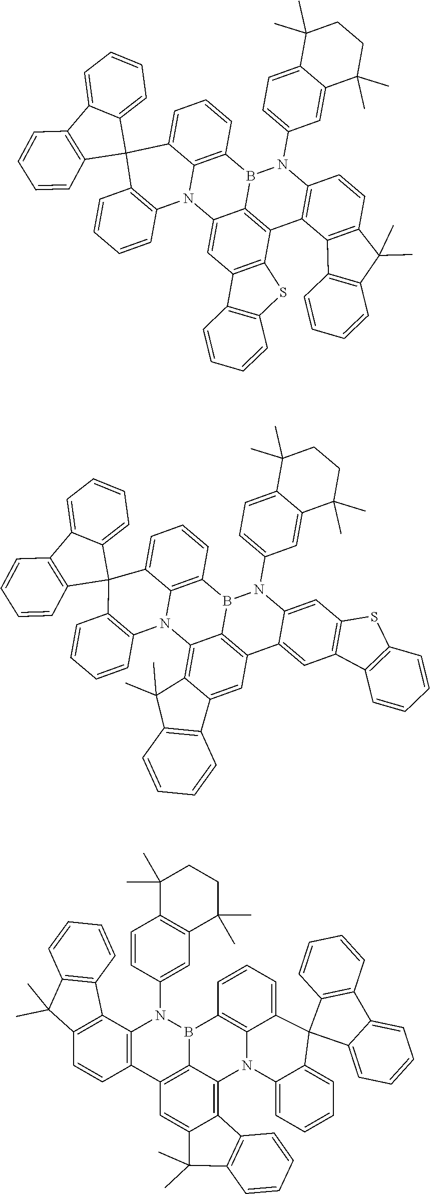 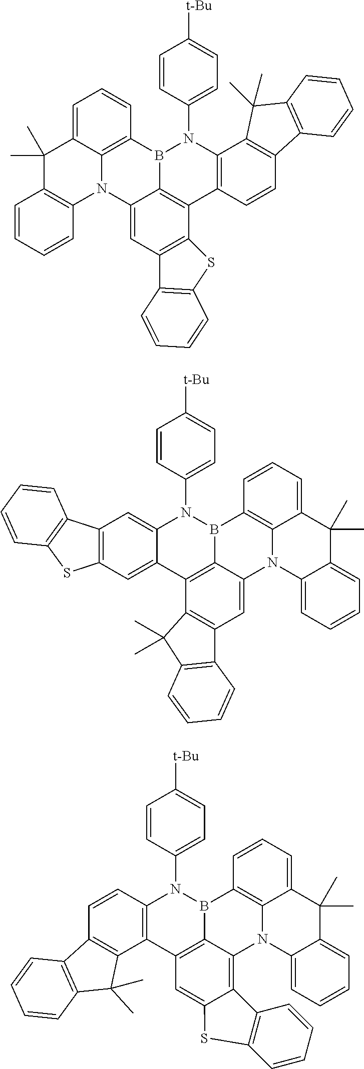 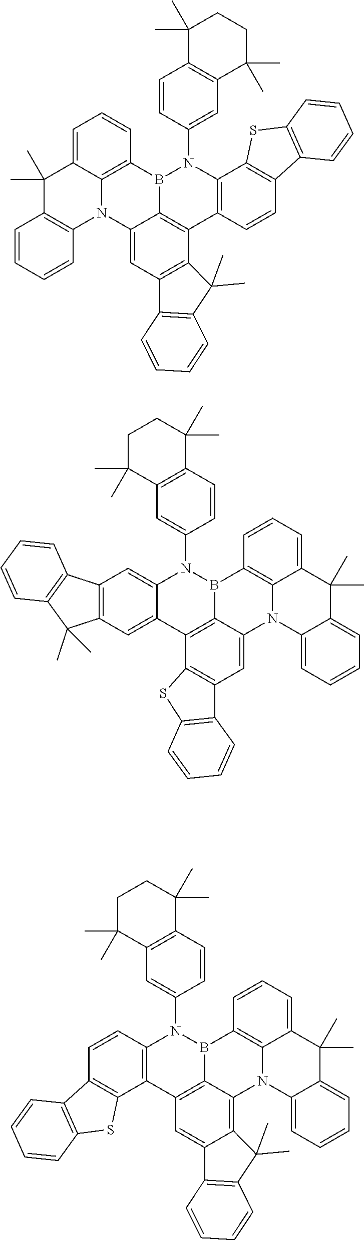 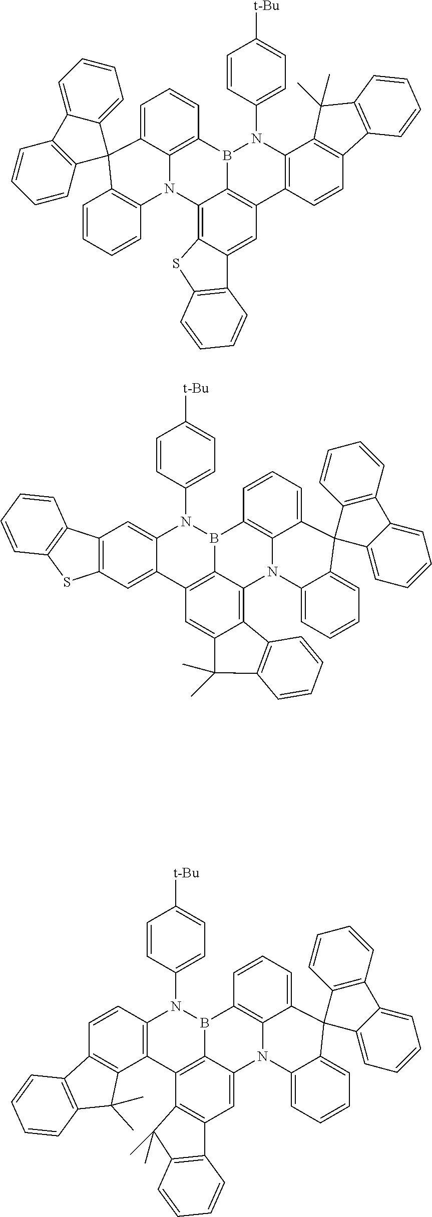 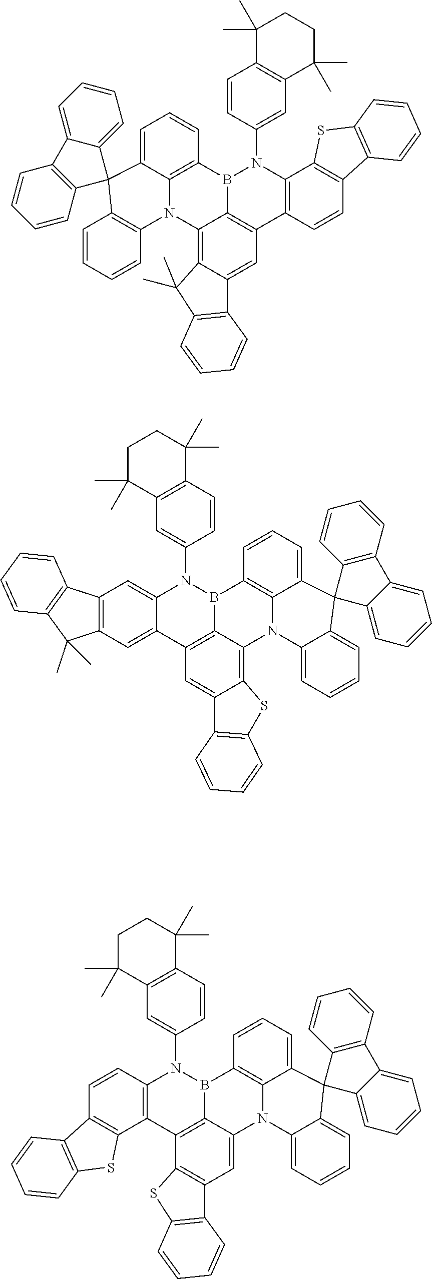 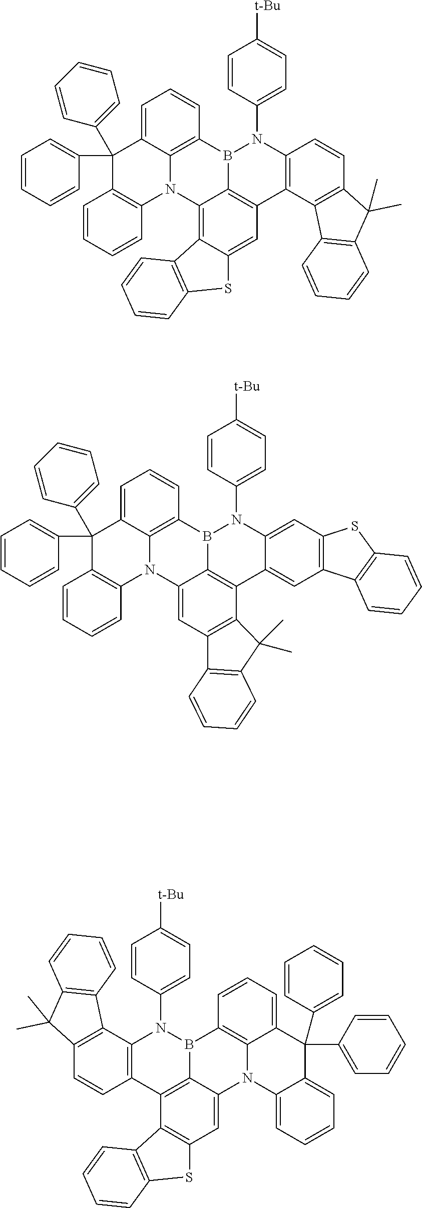 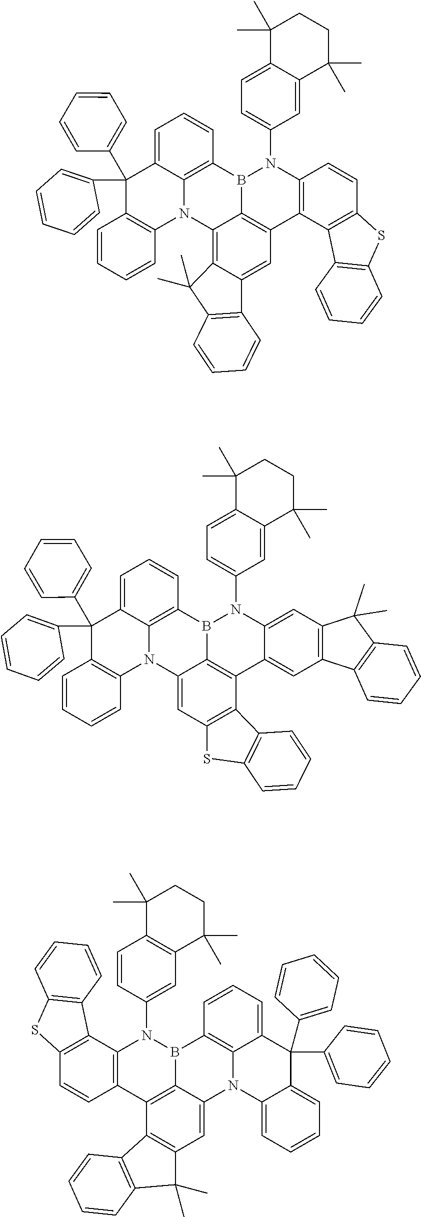 [SMILES: CC1(C)CCC(C)(C)c2cc(N3B4c5cccc6c5N(c5ccccc5C6(c5ccccc5)c5ccccc5)c5c4c(cc4c5C(C)(C)c5ccccc5-4)-c4c3ccc3sc5ccccc5c43)ccc21 ; CC1(C)CCC(C)(C)c2cc(N3B4c5cccc6c5N(c5ccccc5C6(c5ccccc5)c5ccccc5)c5cc6sc7ccccc7c6c(c54)-c4cc5c(cc43)C(C)(C)c3ccccc3-5)ccc21 ; CC1(C)CCC(C)(C)c2cc(N3B4c5cccc6c5N(c5ccccc5C6(c5ccccc5)c5ccccc5)c5cc6c(c(c54)-c4ccc5sc7ccccc7c5c43)-c3ccccc3C6(C)C)ccc21] 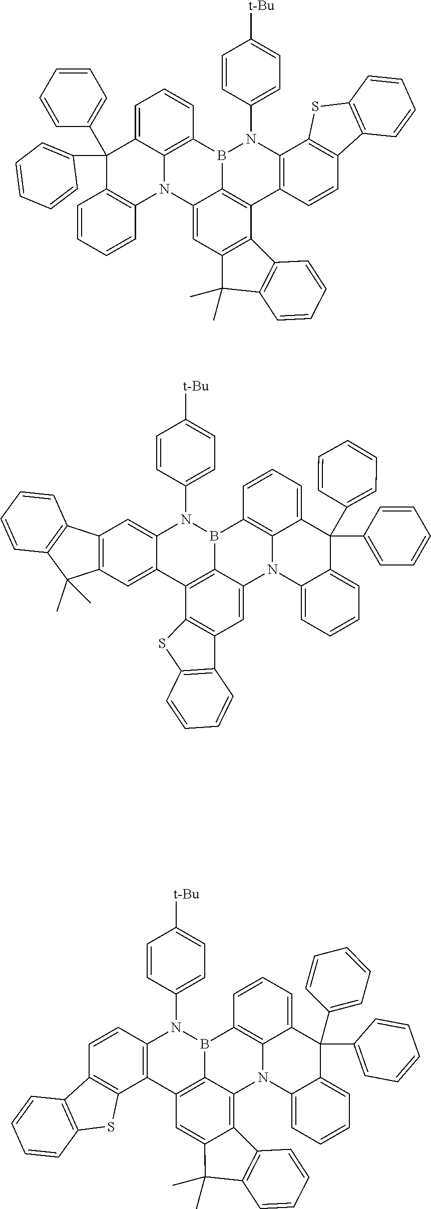 [SMILES: CC(C)(C)c1ccc(N2B3c4cccc5c4N(c4ccccc4C5(c4ccccc4)c4ccccc4)c4cc5c(c(c43)-c3ccc4c(sc6ccccc64)c32)-c2ccccc2C5(C)C)cc1 ; CC(C)(C)c1ccc(N2B3c4cccc5c4N(c4ccccc4C5(c4ccccc4)c4ccccc4)c4cc5c(sc6ccccc65)c(c43)-c3cc4c(cc32)-c2ccccc2C4(C)C)cc1 ; CC(C)(C)c1ccc(N2B3c4cccc5c4N(c4ccccc4C5(c4ccccc4)c4ccccc4)c4c3c(cc3c4-c4ccccc4C3(C)C)-c3c2ccc2c3sc3ccccc32)cc1] 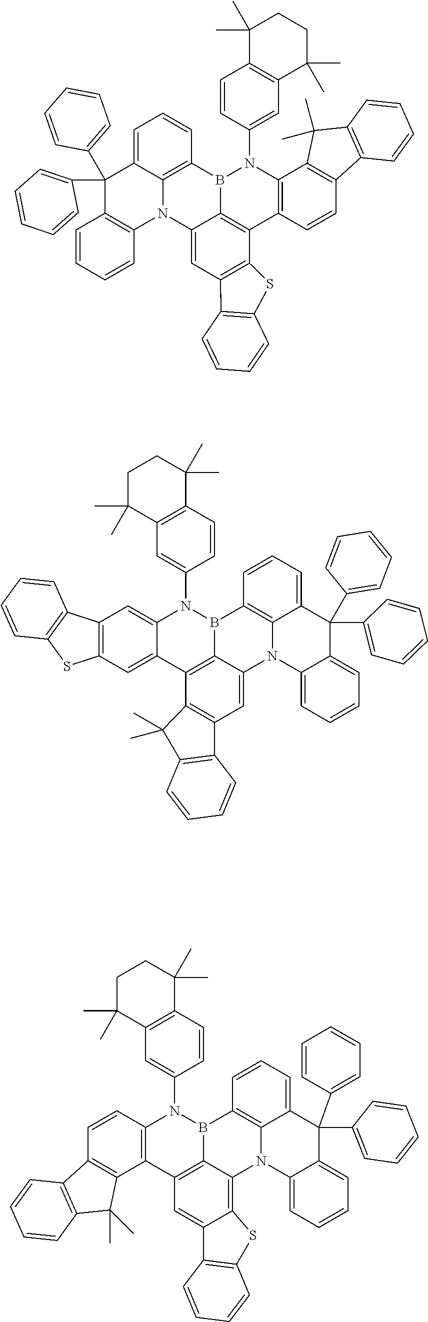 [SMILES: CC1(C)CCC(C)(C)c2cc(N3B4c5cccc6c5N(c5ccccc5C6(c5ccccc5)c5ccccc5)c5cc6c(sc7ccccc76)c(c54)-c4ccc5c(c43)C(C)(C)c3ccccc3-5)ccc21 ; CC1(C)CCC(C)(C)c2cc(N3B4c5cccc6c5N(c5ccccc5C6(c5ccccc5)c5ccccc5)c5cc6c(c(c54)-c4cc5sc7ccccc7c5cc43)C(C)(C)c3ccccc3-6)ccc21 ; CC1(C)CCC(C)(C)c2cc(N3B4c5cccc6c5N(c5ccccc5C6(c5ccccc5)c5ccccc5)c5c4c(cc4c5sc5ccccc54)-c4c3ccc3c4C(C)(C)c4ccccc4-3)ccc21] 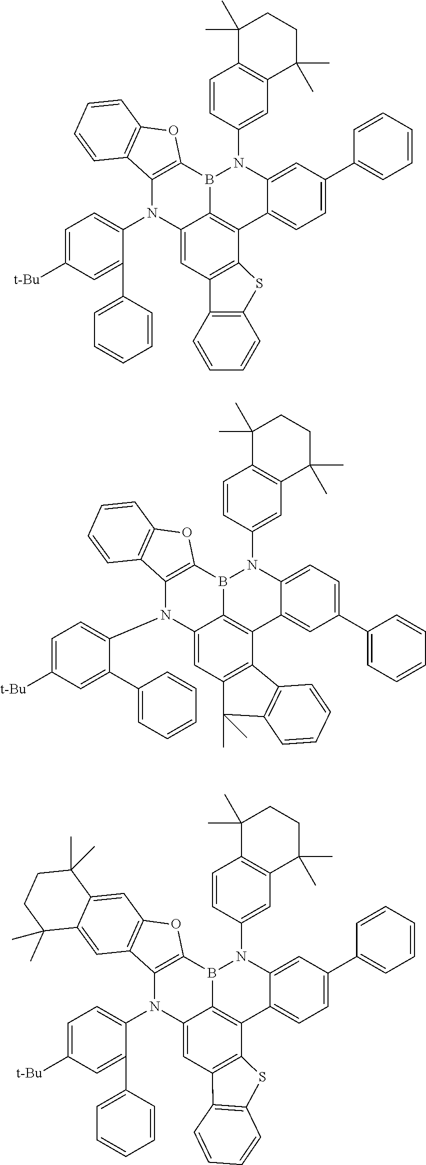 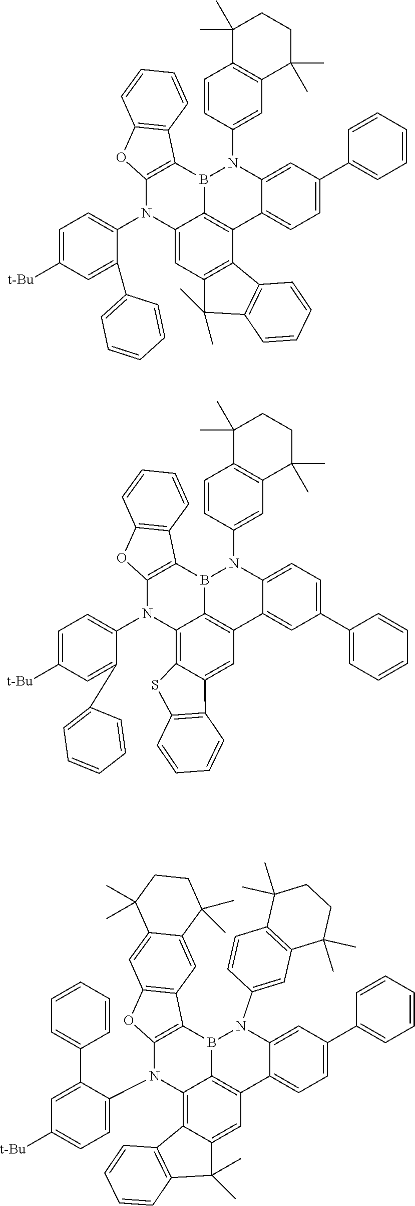 [SMILES: CC(C)(C)c1ccc(N2c3cc4c(c5c3B(c3c2oc2ccccc32)N(c2ccc3c(c2)C(C)(C)CCC3(C)C)c2cc(-c3ccccc3)ccc2-5)-c2ccccc2C4(C)C)c(-c2ccccc2)c1 ; CC(C)(C)c1ccc(N2c3oc4ccccc4c3B3c4c(cc5c(sc6ccccc65)c42)-c2cc(-c4ccccc4)ccc2N3c2ccc3c(c2)C(C)(C)CCC3(C)C)c(-c2ccccc2)c1 ; CC(C)(C)c1ccc(N2c3oc4cc5c(cc4c3B3c4c(cc6c(c42)-c2ccccc2C6(C)C)-c2ccc(-c4ccccc4)cc2N3c2ccc3c(c2)C(C)(C)CCC3(C)C)C(C)(C)CCC5(C)C)c(-c2ccccc2)c1] 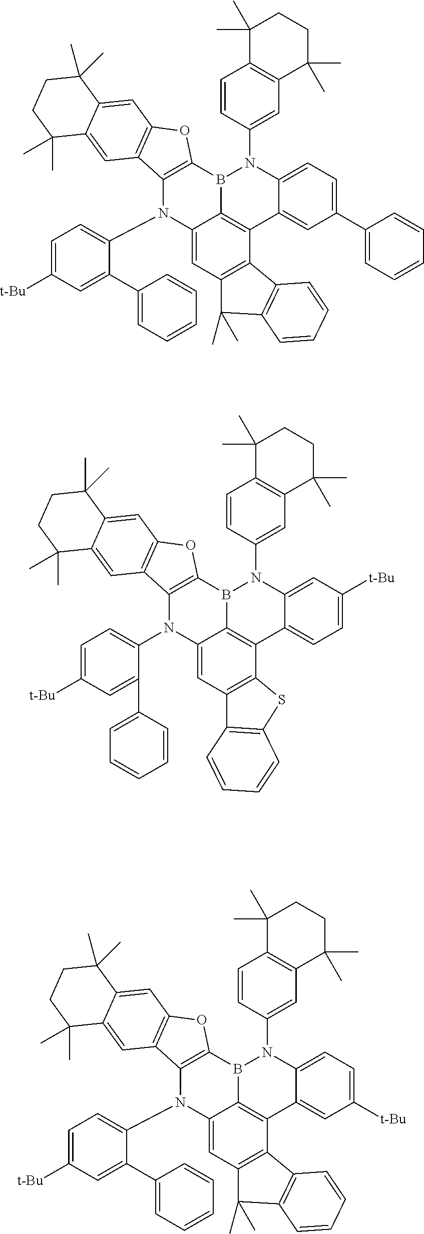 [SMILES: CC(C)(C)c1ccc(N2c3cc4c(c5c3B(c3oc6cc7c(cc6c32)C(C)(C)CCC7(C)C)N(c2ccc3c(c2)C(C)(C)CCC3(C)C)c2ccc(-c3ccccc3)cc2-5)-c2ccccc2C4(C)C)c(-c2ccccc2)c1 ; CC(C)(C)c1ccc(N2c3cc4c(sc5ccccc54)c4c3B(c3oc5cc6c(cc5c32)C(C)(C)CCC6(C)C)N(c2ccc3c(c2)C(C)(C)CCC3(C)C)c2cc(C(C)(C)C)ccc2-4)c(-c2ccccc2)c1 ; CC(C)(C)c1ccc2c(c1)-c1c3c(cc4c1-c1ccccc1C4(C)C)N(c1ccc(C(C)(C)C)cc1-c1ccccc1)c1c(oc4cc5c(cc14)C(C)(C)CCC5(C)C)B3N2c1ccc2c(c1)C(C)(C)CCC2(C)C] 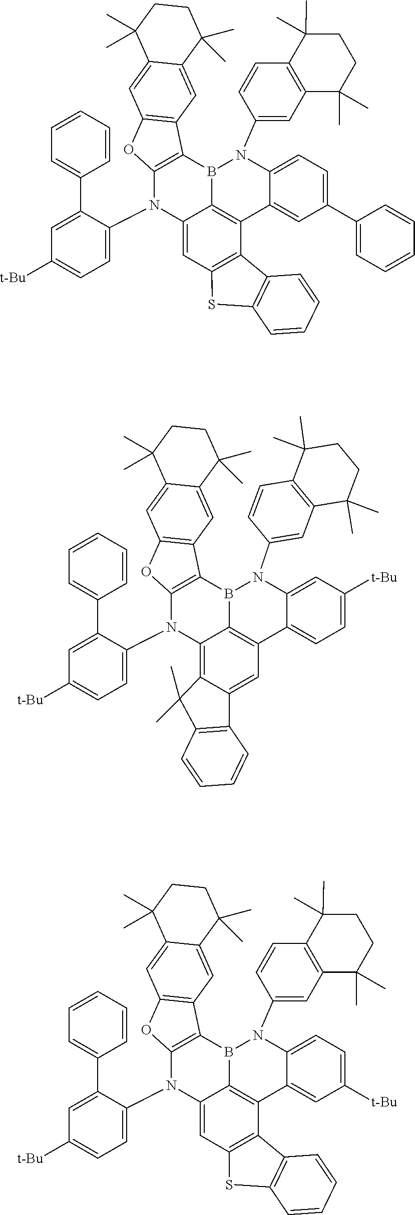 [SMILES: CC(C)(C)c1ccc(N2c3cc4sc5ccccc5c4c4c3B(c3c2oc2cc5c(cc32)C(C)(C)CCC5(C)C)N(c2ccc3c(c2)C(C)(C)CCC3(C)C)c2ccc(-c3ccccc3)cc2-4)c(-c2ccccc2)c1 ; CC(C)(C)c1ccc(N2c3oc4cc5c(cc4c3B3c4c(cc6c(c42)C(C)(C)c2ccccc2-6)-c2ccc(C(C)(C)C)cc2N3c2ccc3c(c2)C(C)(C)CCC3(C)C)C(C)(C)CCC5(C)C)c(-c2ccccc2)c1 ; CC(C)(C)c1ccc2c(c1)-c1c3c(cc4sc5ccccc5c14)N(c1ccc(C(C)(C)C)cc1-c1ccccc1)c1oc4cc5c(cc4c1B3N2c1ccc2c(c1)C(C)(C)CCC2(C)C)C(C)(C)CCC5(C)C] 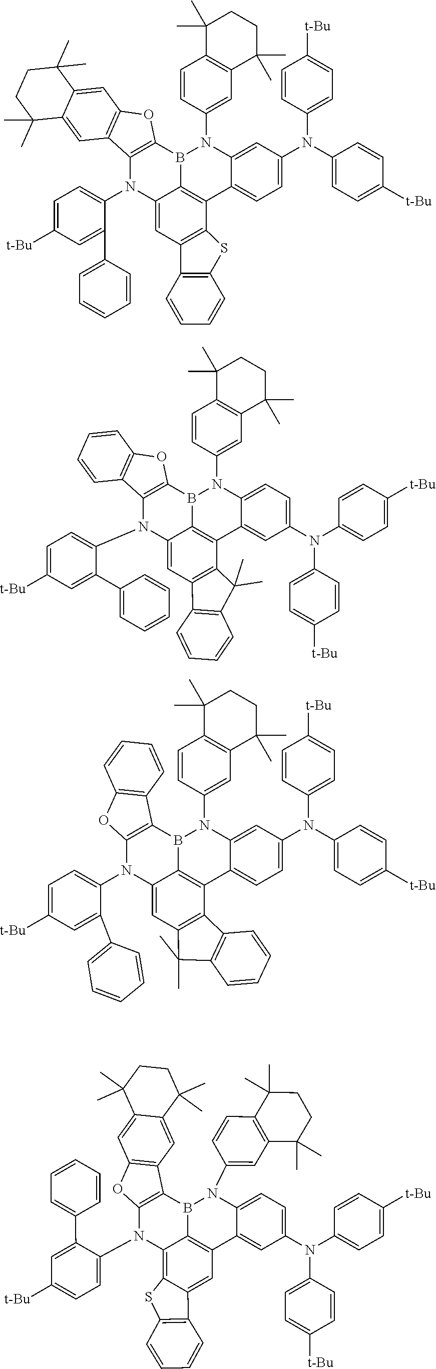 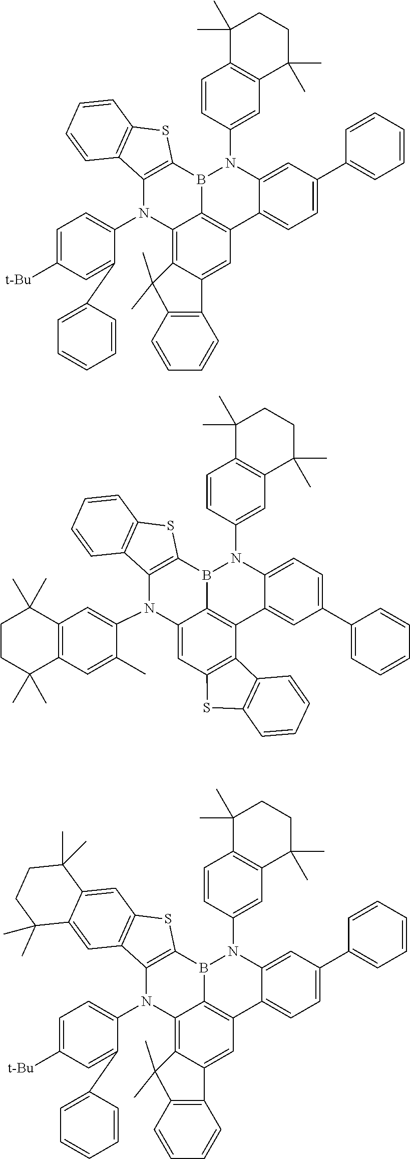 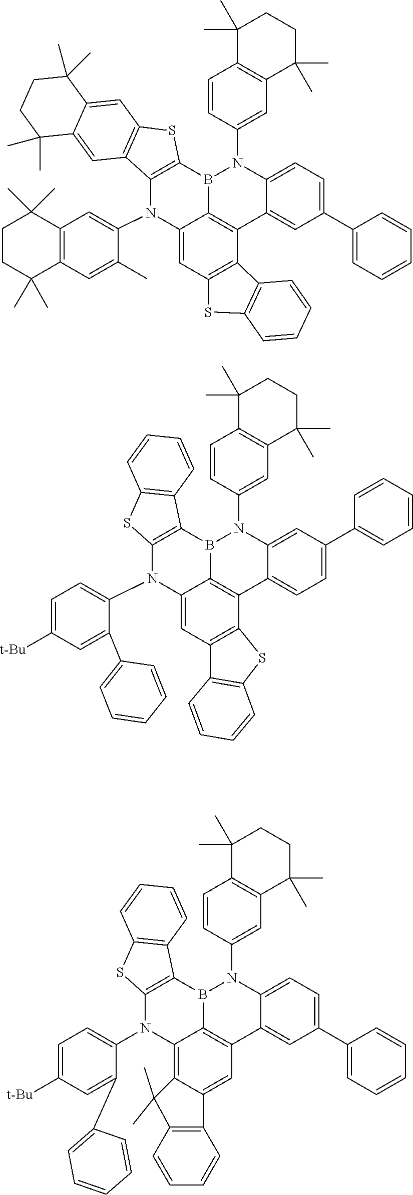 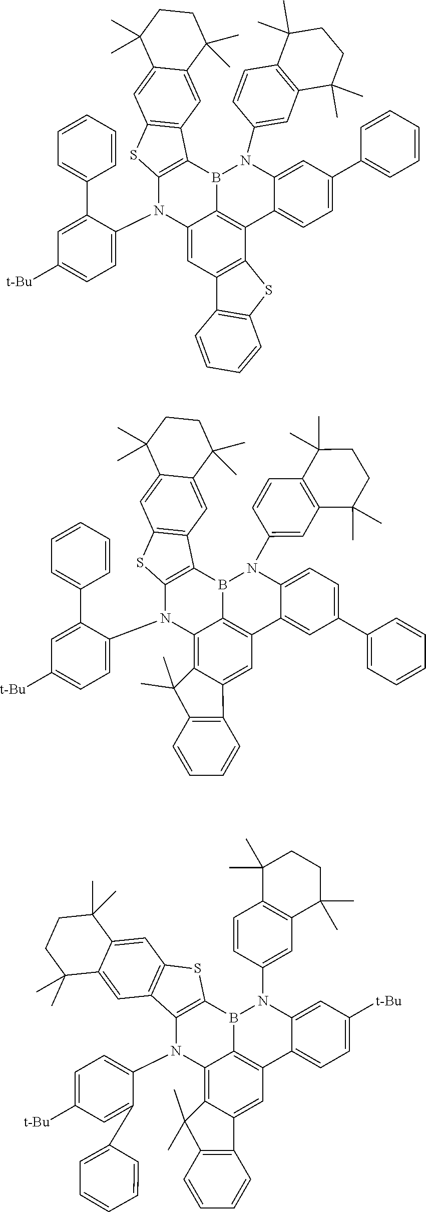 [SMILES: CC(C)(C)c1ccc(N2c3cc4c(sc5ccccc54)c4c3B(c3c2sc2cc5c(cc32)C(C)(C)CCC5(C)C)N(c2ccc3c(c2)C(C)(C)CCC3(C)C)c2cc(-c3ccccc3)ccc2-4)c(-c2ccccc2)c1 ; CC(C)(C)c1ccc(N2c3sc4cc5c(cc4c3B3c4c(cc6c(c42)C(C)(C)c2ccccc2-6)-c2cc(-c4ccccc4)ccc2N3c2ccc3c(c2)C(C)(C)CCC3(C)C)C(C)(C)CCC5(C)C)c(-c2ccccc2)c1 ; CC(C)(C)c1ccc(N2c3c4c(cc5c3C(C)(C)c3ccccc3-5)-c3ccc(C(C)(C)C)cc3N(c3ccc5c(c3)C(C)(C)CCC5(C)C)B4c3sc4cc5c(cc4c32)C(C)(C)CCC5(C)C)c(-c2ccccc2)c1] 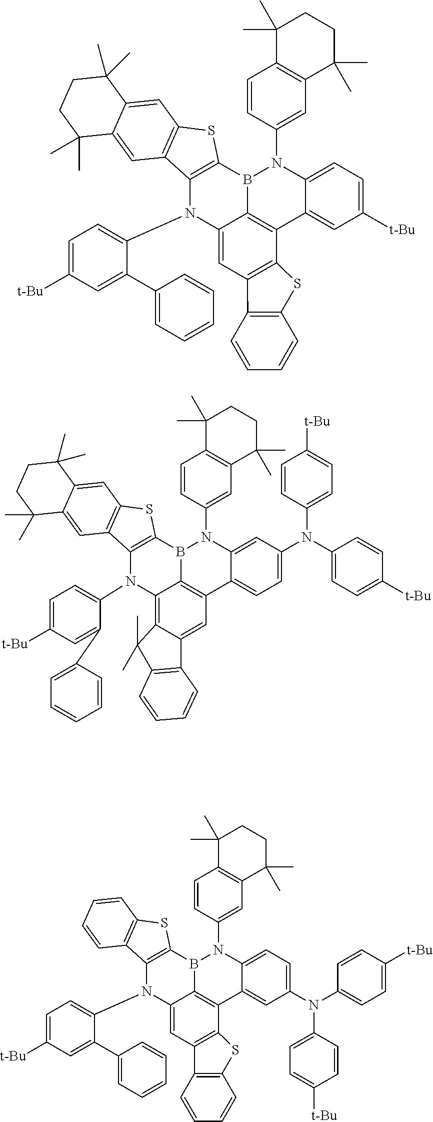 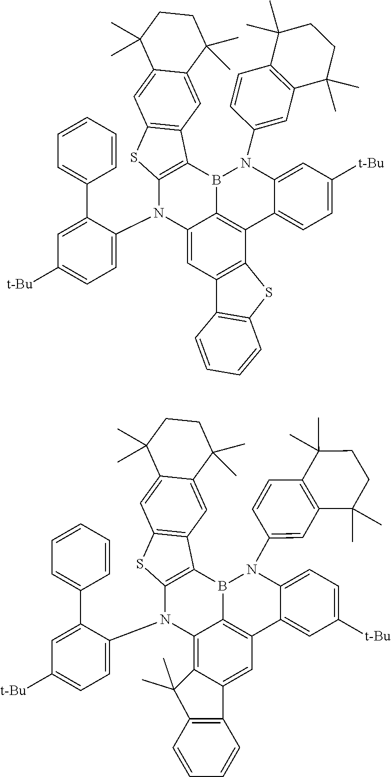 [SMILES: CC(C)(C)c1ccc(N2c3cc4c(sc5ccccc54)c4c3B(c3c2sc2cc5c(cc32)C(C)(C)CCC5(C)C)N(c2ccc3c(c2)C(C)(C)CCC3(C)C)c2cc(C(C)(C)C)ccc2-4)c(-c2ccccc2)c1 ; CC(C)(C)c1ccc2c(c1)-c1cc3c(c4c1B(c1c(sc5cc6c(cc15)C(C)(C)CCC6(C)C)N4c1ccc(C(C)(C)C)cc1-c1ccccc1)N2c1ccc2c(c1)C(C)(C)CCC2(C)C)C(C)(C)c1ccccc1-3] 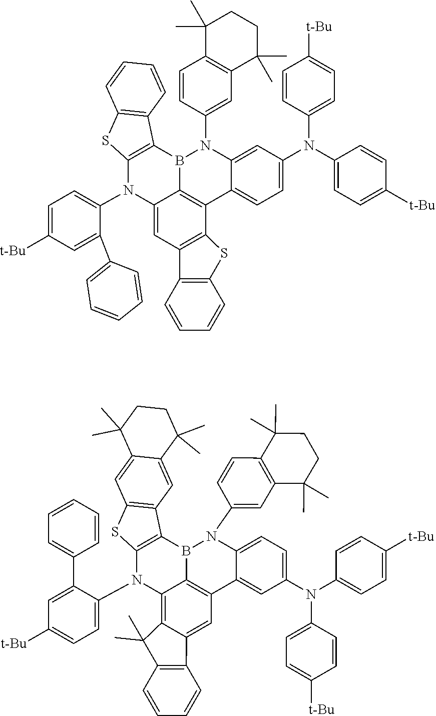 [SMILES: CC(C)(C)c1ccc(N(c2ccc(C(C)(C)C)cc2)c2ccc3c(c2)N(c2ccc4c(c2)C(C)(C)CCC4(C)C)B2c4c(cc5c(sc6ccccc65)c4-3)N(c3ccc(C(C)(C)C)cc3-c3ccccc3)c3sc4ccccc4c32)cc1 ; CC(C)(C)c1ccc(N(c2ccc(C(C)(C)C)cc2)c2ccc3c(c2)-c2cc4c(c5c2B(c2c(sc6cc7c(cc26)C(C)(C)CCC7(C)C)N5c2ccc(C(C)(C)C)cc2-c2ccccc2)N3c2ccc3c(c2)C(C)(C)CCC3(C)C)C(C)(C)c2ccccc2-4)cc1] 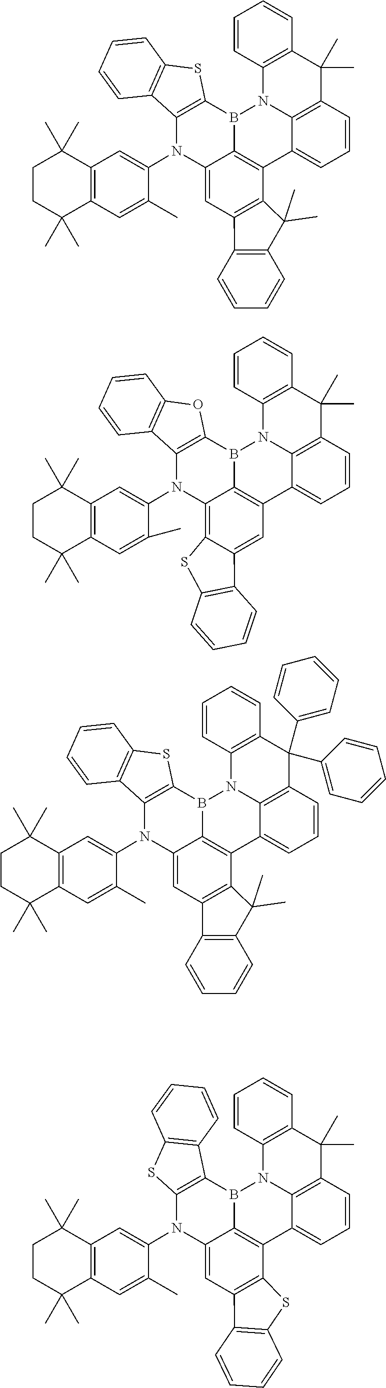 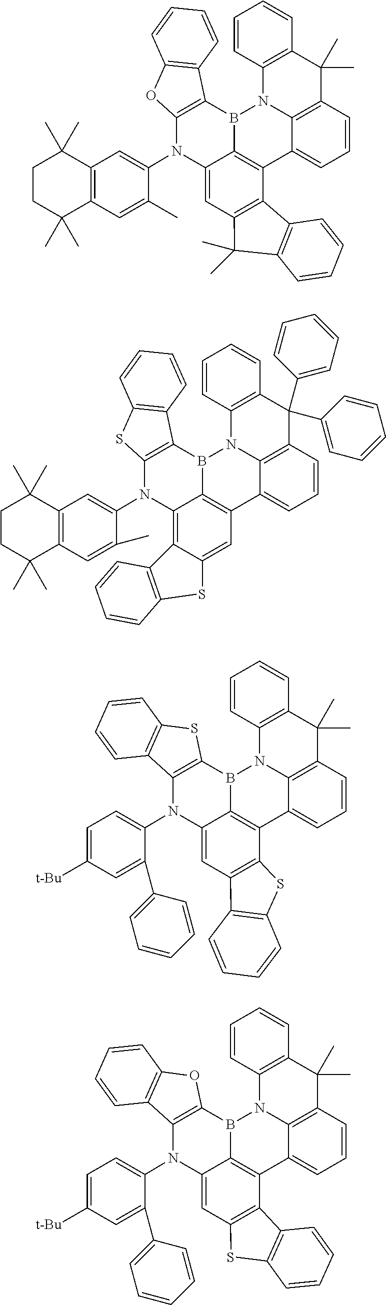 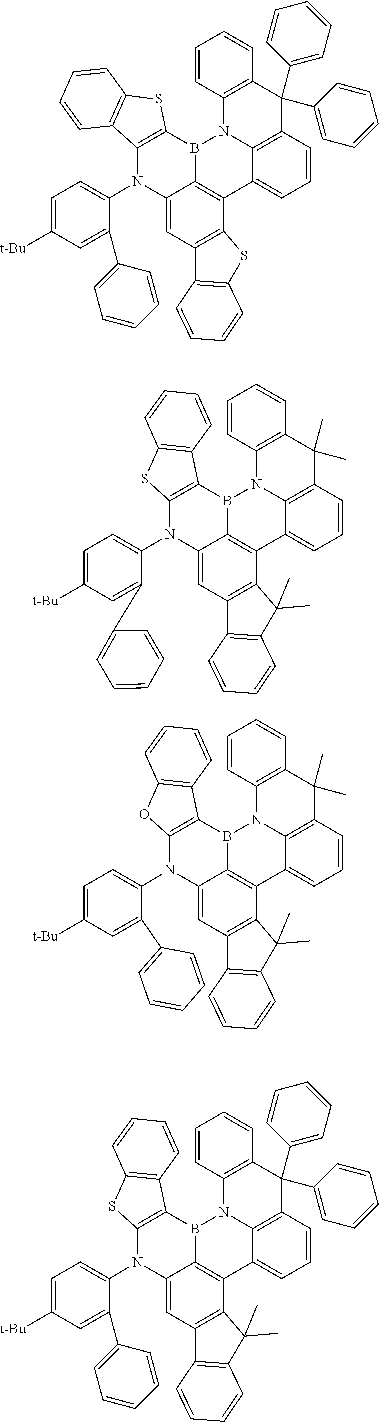 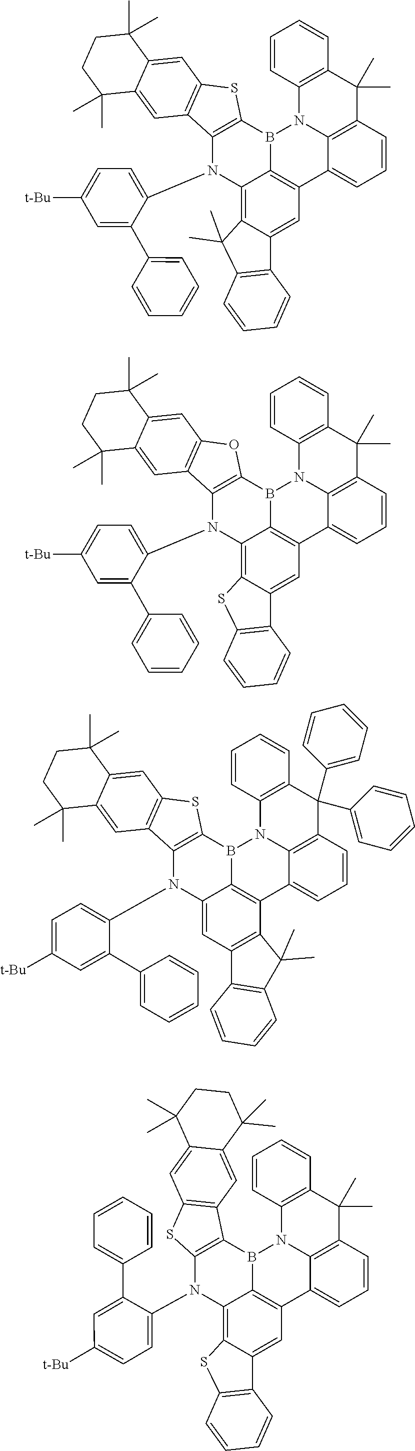 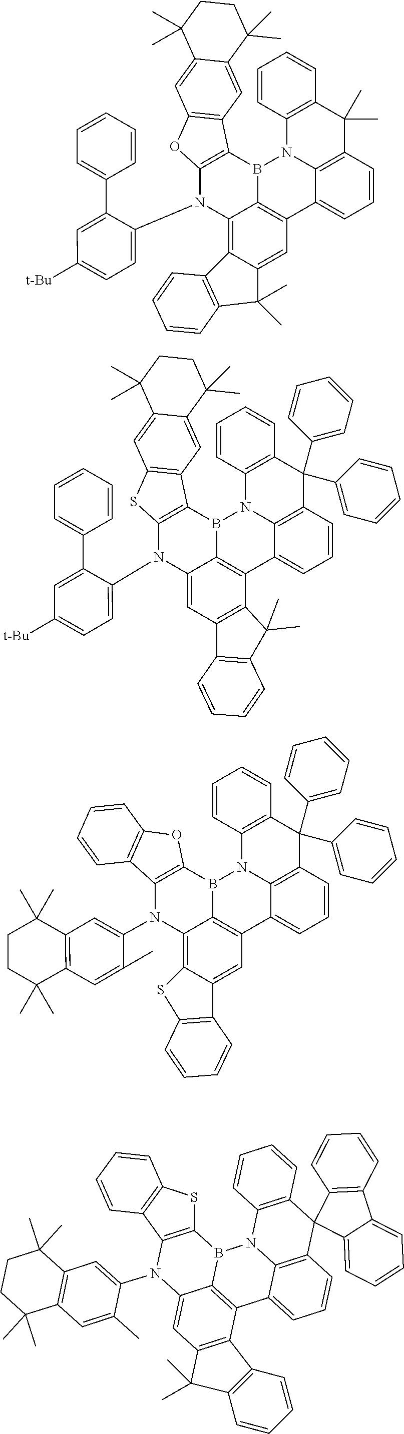 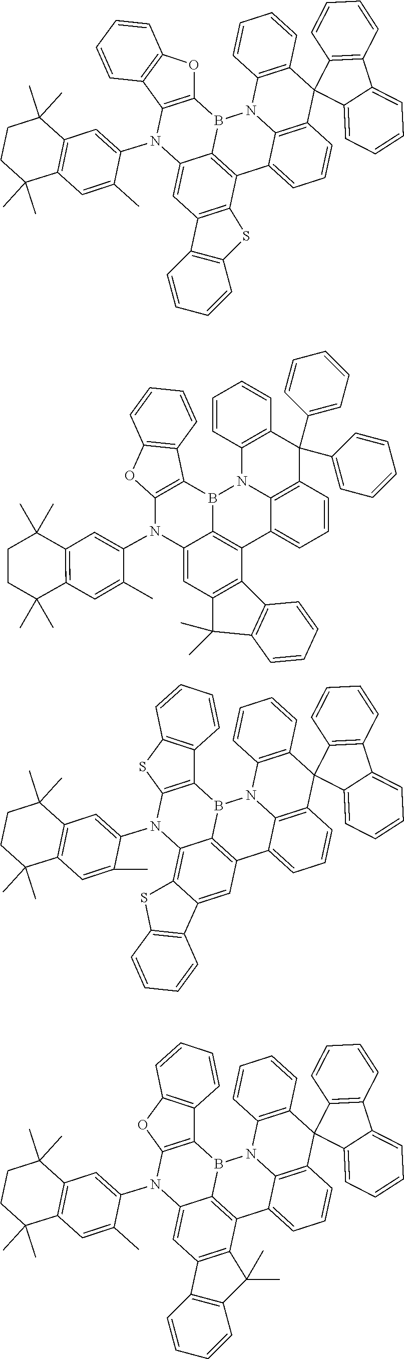 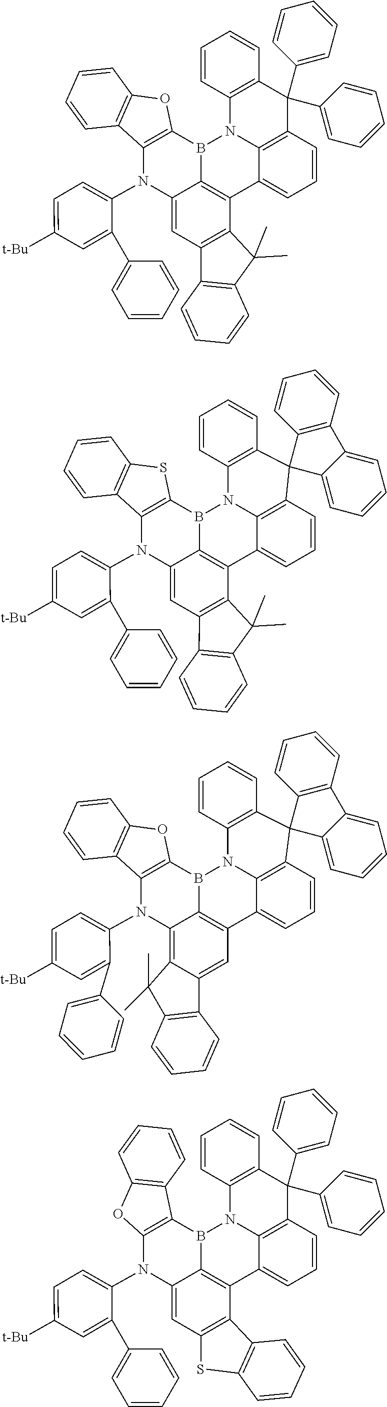 [SMILES: CC(C)(C)c1ccc(N2c3cc4c(c5c3B(c3oc6ccccc6c32)N2c3ccccc3C(c3ccccc3)(c3ccccc3)c3cccc-5c32)C(C)(C)c2ccccc2-4)c(-c2ccccc2)c1 ; CC(C)(C)c1ccc(N2c3cc4c(c5c3B(c3sc6ccccc6c32)N2c3ccccc3C3(c6ccccc6-c6ccccc63)c3cccc-5c32)C(C)(C)c2ccccc2-4)c(-c2ccccc2)c1 ; CC(C)(C)c1ccc(N2c3c4c(cc5c3C(C)(C)c3ccccc3-5)-c3cccc5c3N(B4c3oc4ccccc4c32)c2ccccc2C52c3ccccc3-c3ccccc32)c(-c2ccccc2)c1 ; CC(C)(C)c1ccc(N2c3cc4sc5ccccc5c4c4c3B(c3c2oc2ccccc32)N2c3ccccc3C(c3ccccc3)(c3ccccc3)c3cccc-4c32)c(-c2ccccc2)c1] 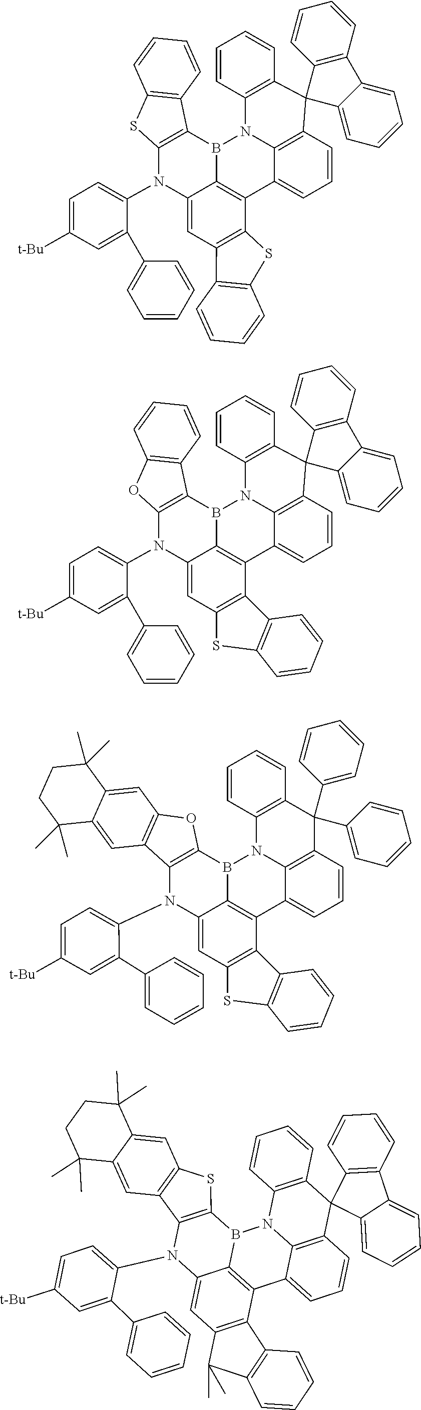 [SMILES: CC(C)(C)c1ccc(N2c3cc4c(sc5ccccc54)c4c3B(c3c2sc2ccccc32)N2c3ccccc3C3(c5ccccc5-c5ccccc53)c3cccc-4c32)c(-c2ccccc2)c1 ; CC(C)(C)c1ccc(N2c3cc4sc5ccccc5c4c4c3B(c3c2oc2ccccc32)N2c3ccccc3C3(c5ccccc5-c5ccccc53)c3cccc-4c32)c(-c2ccccc2)c1 ; CC(C)(C)c1ccc(N2c3cc4sc5ccccc5c4c4c3B(c3oc5cc6c(cc5c32)C(C)(C)CCC6(C)C)N2c3ccccc3C(c3ccccc3)(c3ccccc3)c3cccc-4c32)c(-c2ccccc2)c1 ; CC(C)(C)c1ccc(N2c3cc4c(c5c3B(c3sc6cc7c(cc6c32)C(C)(C)CCC7(C)C)N2c3ccccc3C3(c6ccccc6-c6ccccc63)c3cccc-5c32)-c2ccccc2C4(C)C)c(-c2ccccc2)c1] 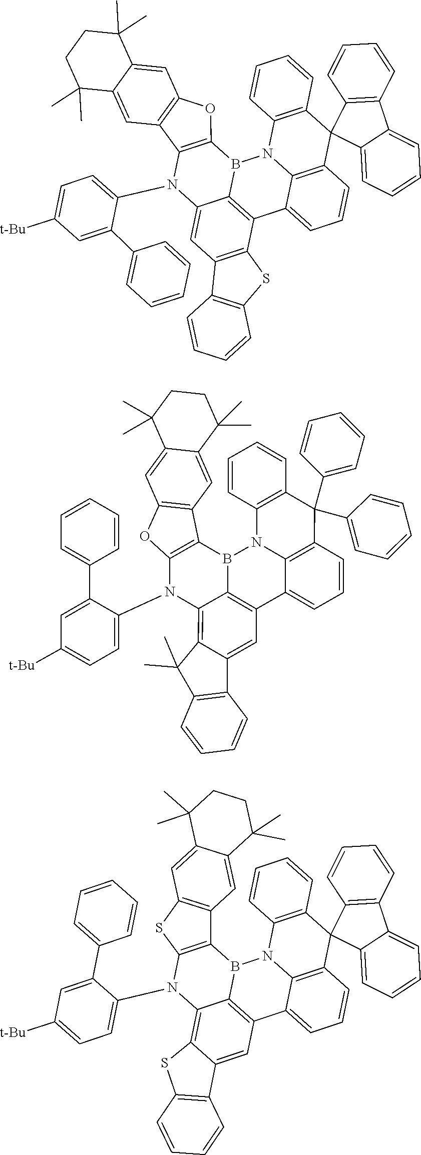 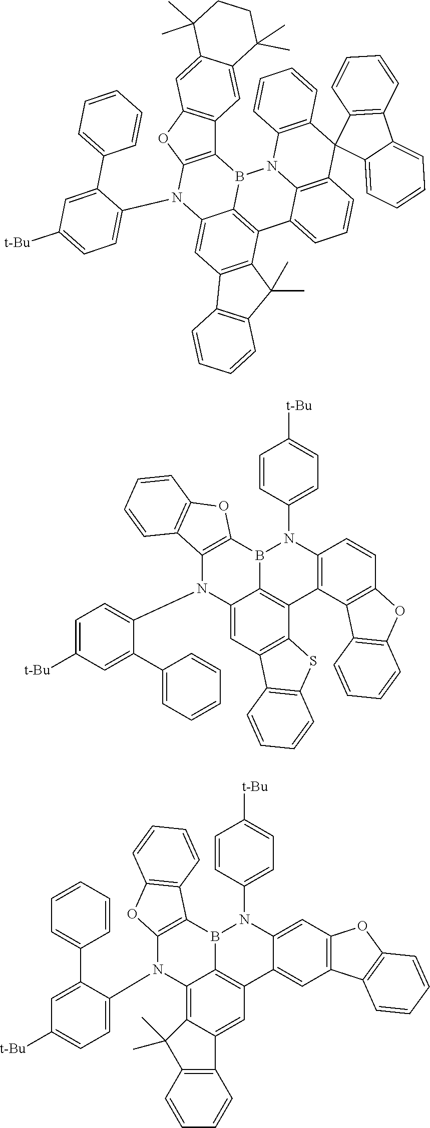 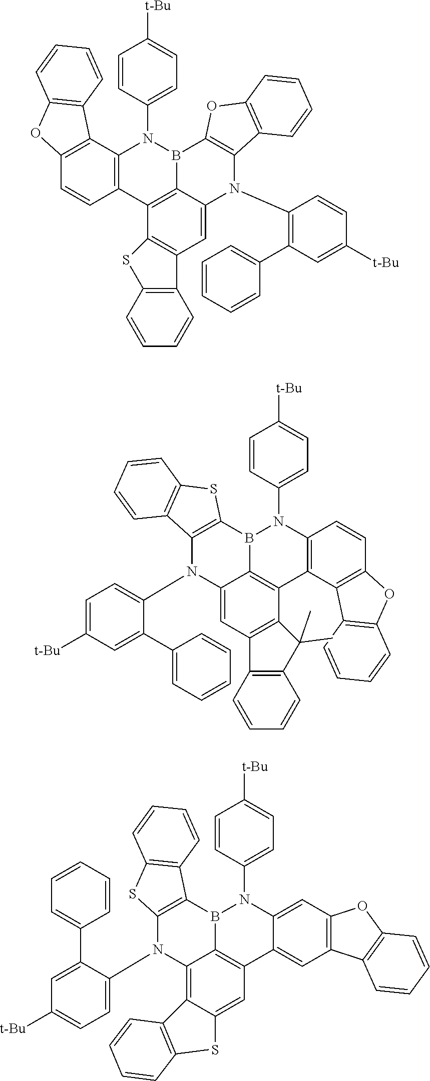 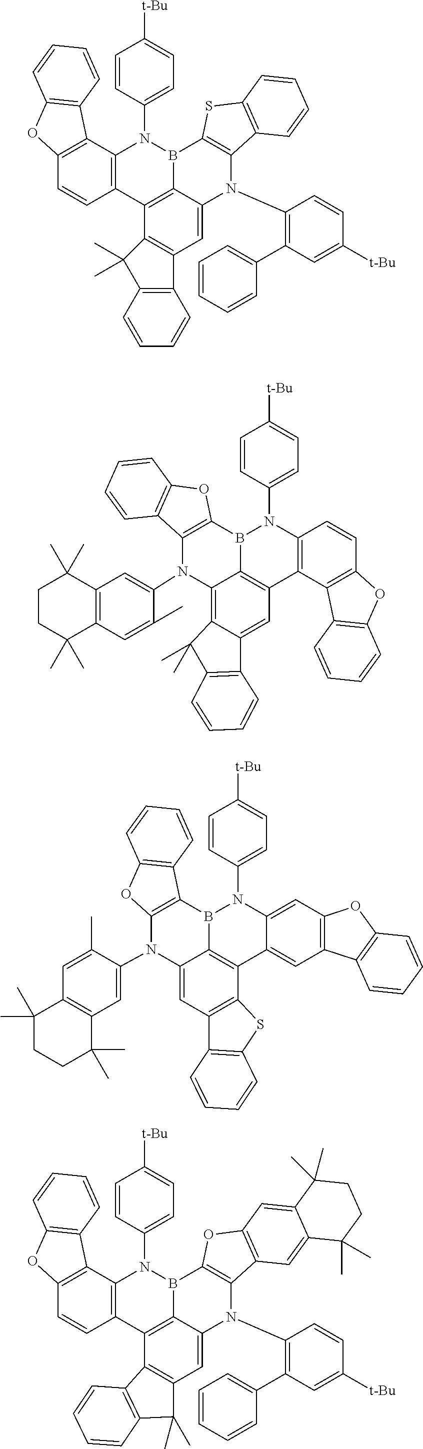 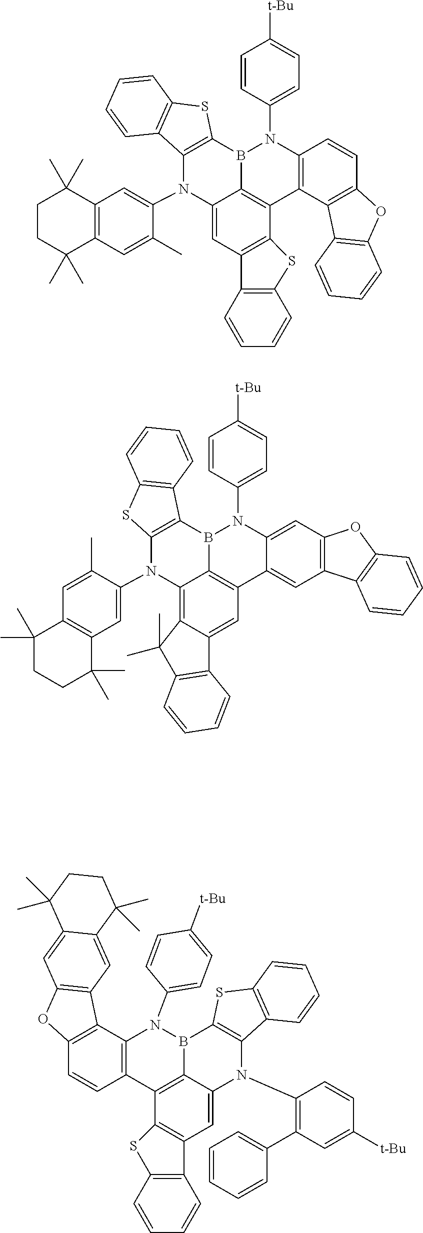 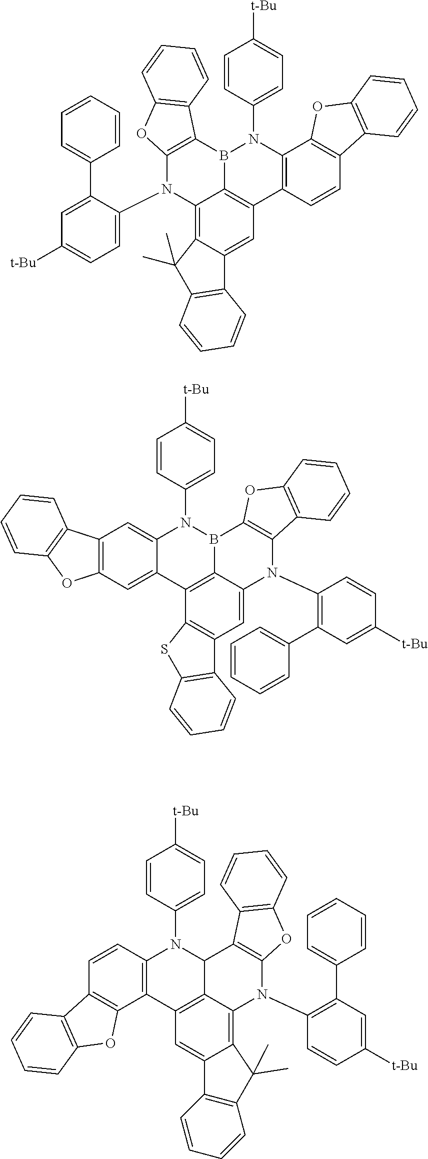 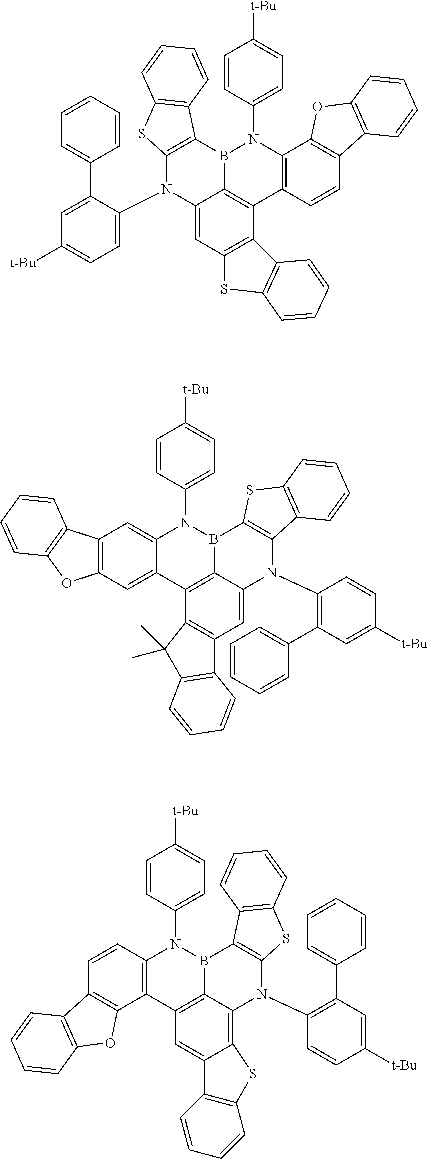 [SMILES: CC(C)(C)c1ccc(N2B3c4c(cc5sc6ccccc6c5c4-c4ccc5c(oc6ccccc65)c42)N(c2ccc(C(C)(C)C)cc2-c2ccccc2)c2sc4ccccc4c23)cc1 ; CC(C)(C)c1ccc(N2B3c4sc5ccccc5c4N(c4ccc(C(C)(C)C)cc4-c4ccccc4)c4cc5c(c(c43)-c3cc4oc6ccccc6c4cc32)C(C)(C)c2ccccc2-5)cc1 ; CC(C)(C)c1ccc(N2B3c4c(cc5c(sc6ccccc65)c4N(c4ccc(C(C)(C)C)cc4-c4ccccc4)c4sc5ccccc5c43)-c3c2ccc2c3oc3ccccc32)cc1] 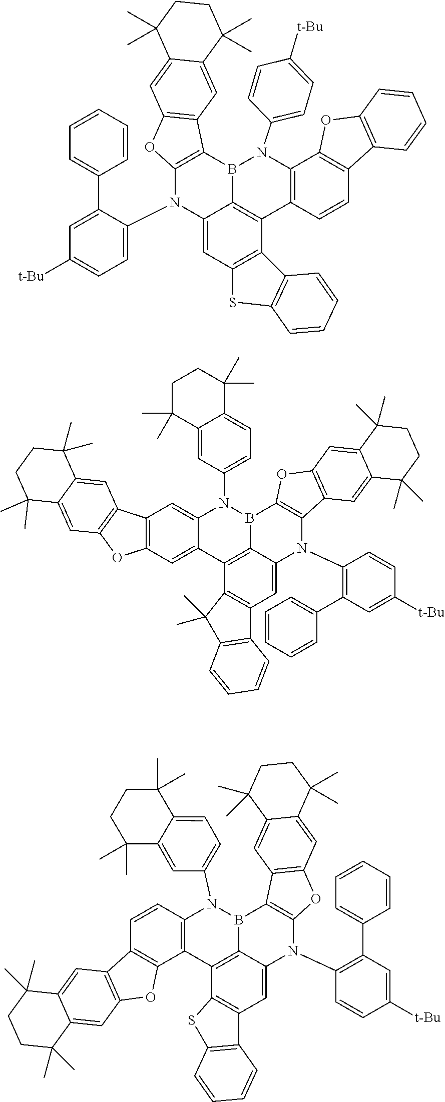 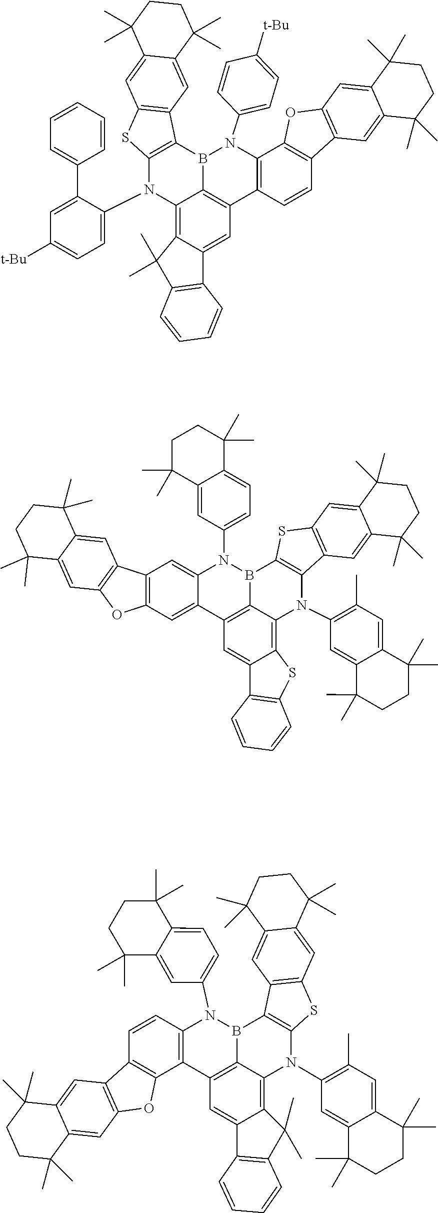 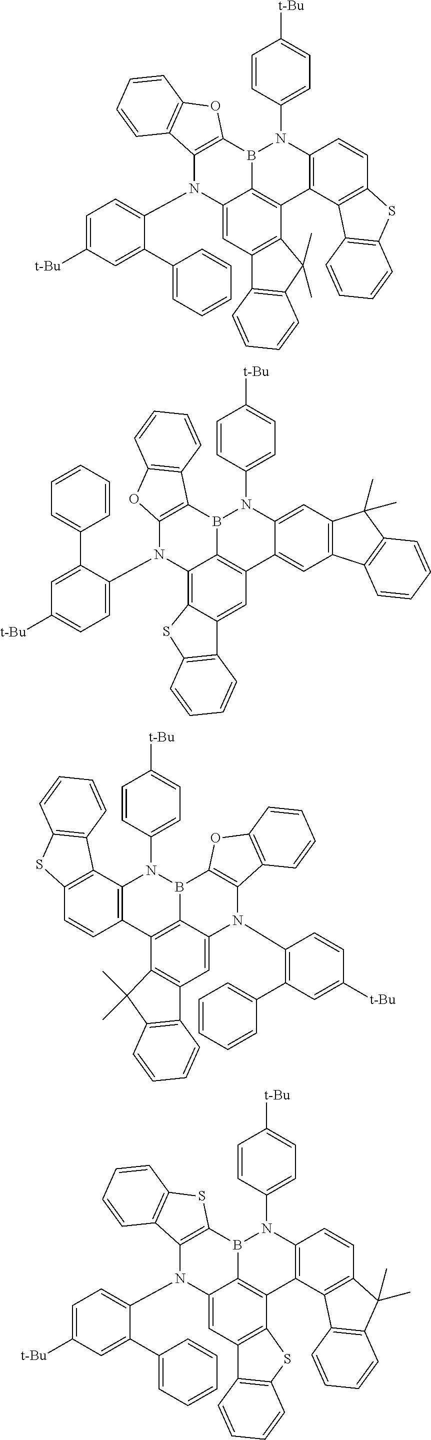 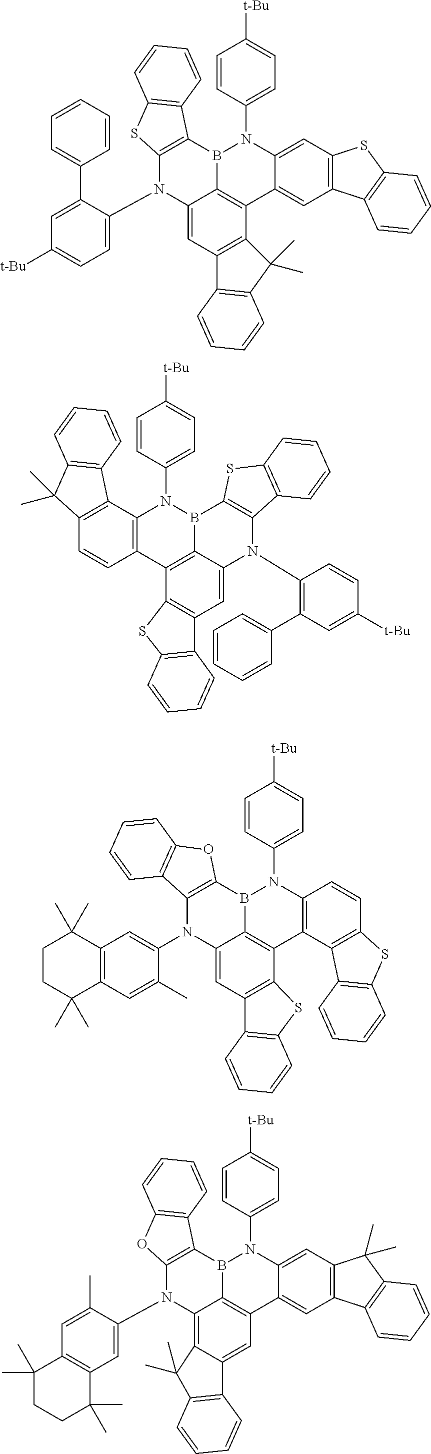 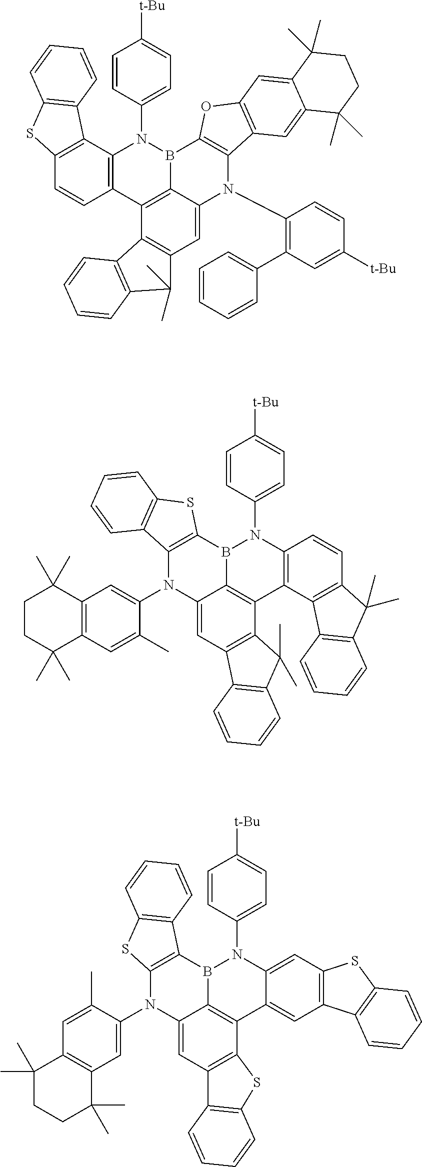 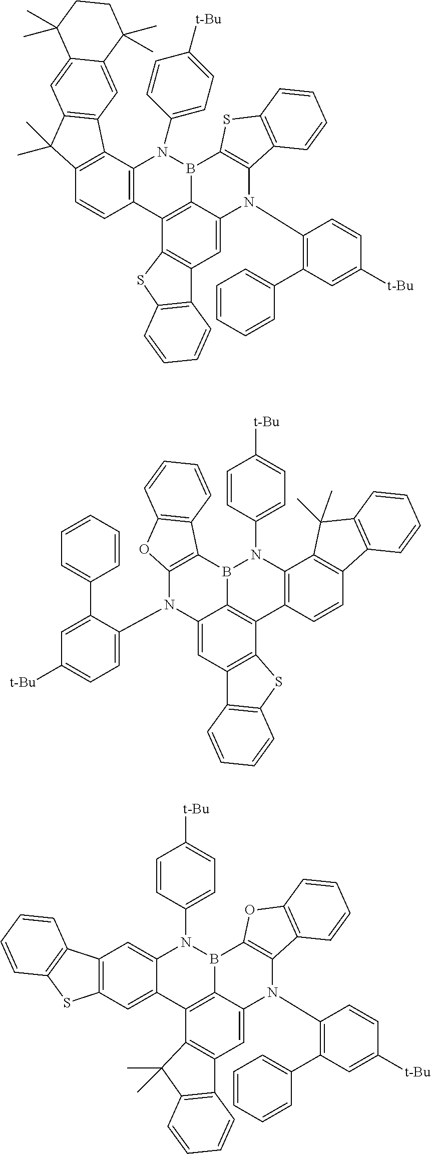 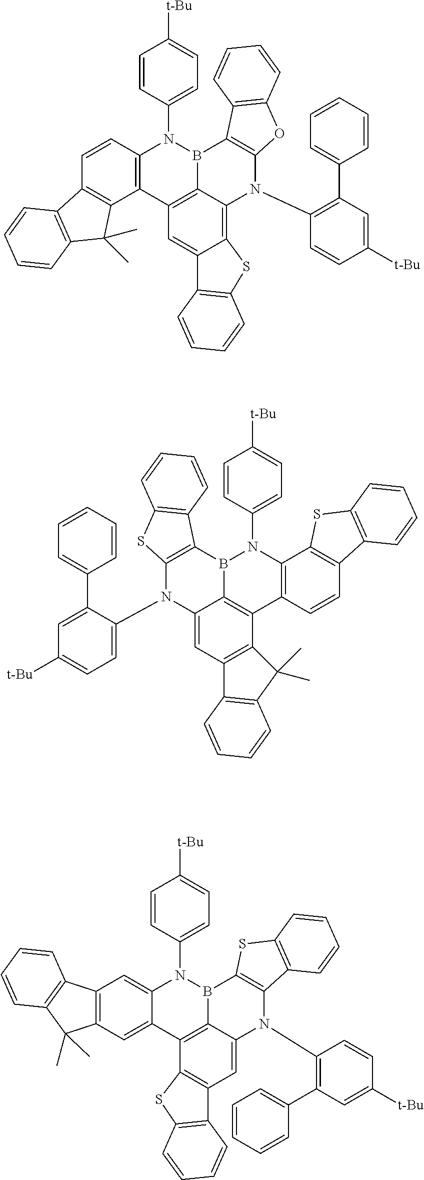 [SMILES: CC(C)(C)c1ccc(N2B3c4c(cc5c(sc6ccccc65)c4N(c4ccc(C(C)(C)C)cc4-c4ccccc4)c4oc5ccccc5c43)-c3c2ccc2c3C(C)(C)c3ccccc3-2)cc1 ; CC(C)(C)c1ccc(N2B3c4c(cc5c(c4-c4ccc6c(sc7ccccc76)c42)C(C)(C)c2ccccc2-5)N(c2ccc(C(C)(C)C)cc2-c2ccccc2)c2sc4ccccc4c23)cc1 ; CC(C)(C)c1ccc(N2B3c4sc5ccccc5c4N(c4ccc(C(C)(C)C)cc4-c4ccccc4)c4cc5c(sc6ccccc65)c(c43)-c3cc4c(cc32)-c2ccccc2C4(C)C)cc1] 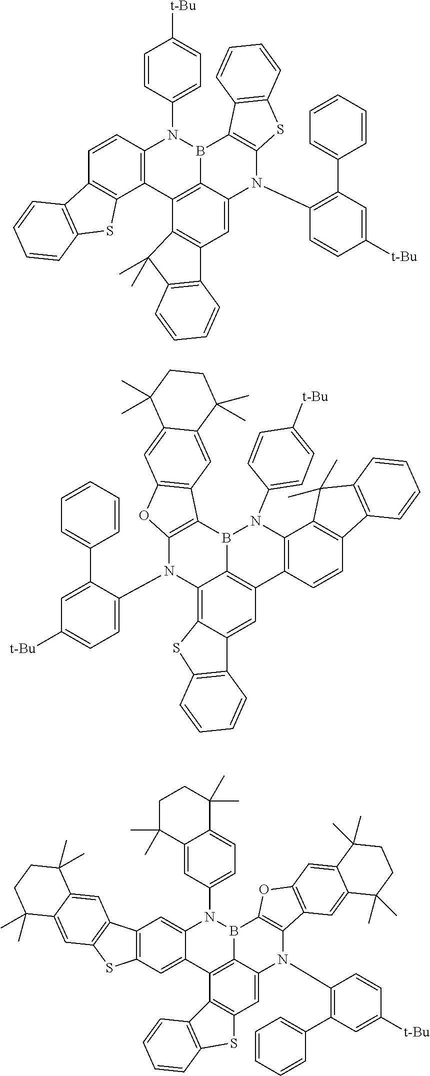 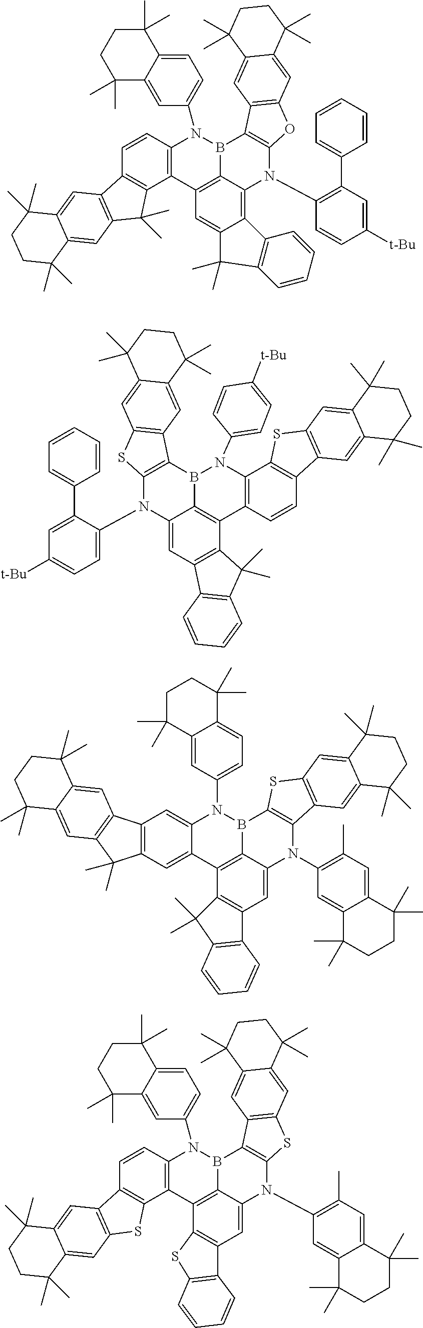 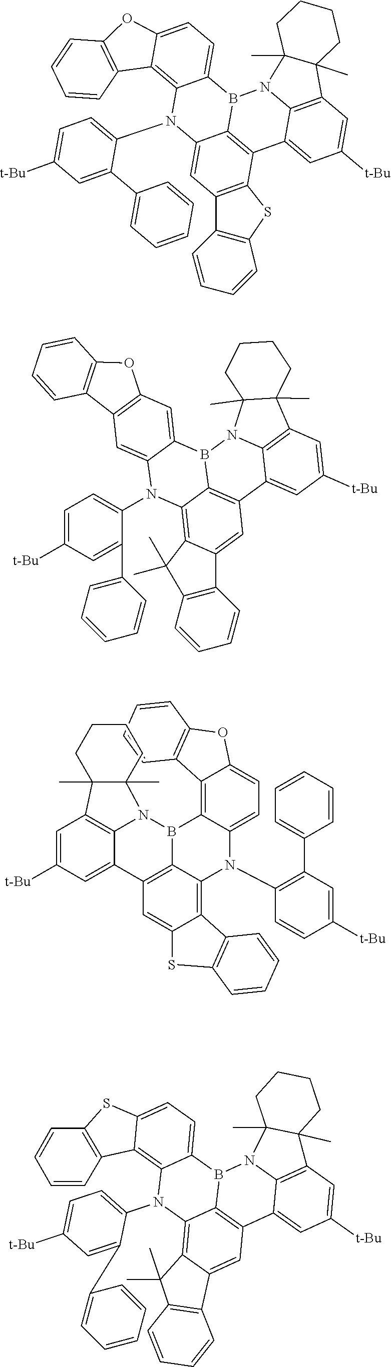 [SMILES: CC(C)(C)c1ccc(N2c3cc4c(sc5ccccc54)c4c3B(c3ccc5oc6ccccc6c5c32)N2c3c-4cc(C(C)(C)C)cc3C3(C)CCCCC23C)c(-c2ccccc2)c1 ; CC(C)(C)c1ccc(N2c3cc4c(cc3B3c5c(cc6c(c52)C(C)(C)c2ccccc2-6)-c2cc(C(C)(C)C)cc5c2N3C2(C)CCCCC52C)oc2ccccc24)c(-c2ccccc2)c1 ; CC(C)(C)c1ccc(N2c3ccc4oc5ccccc5c4c3B3c4c(cc5sc6ccccc6c5c42)-c2cc(C(C)(C)C)cc4c2N3C2(C)CCCCC42C)c(-c2ccccc2)c1 ; CC(C)(C)c1ccc(N2c3c4c(cc5c3C(C)(C)c3ccccc3-5)-c3cc(C(C)(C)C)cc5c3N(B4c3ccc4sc6ccccc6c4c32)C2(C)CCCCC52C)c(-c2ccccc2)c1] 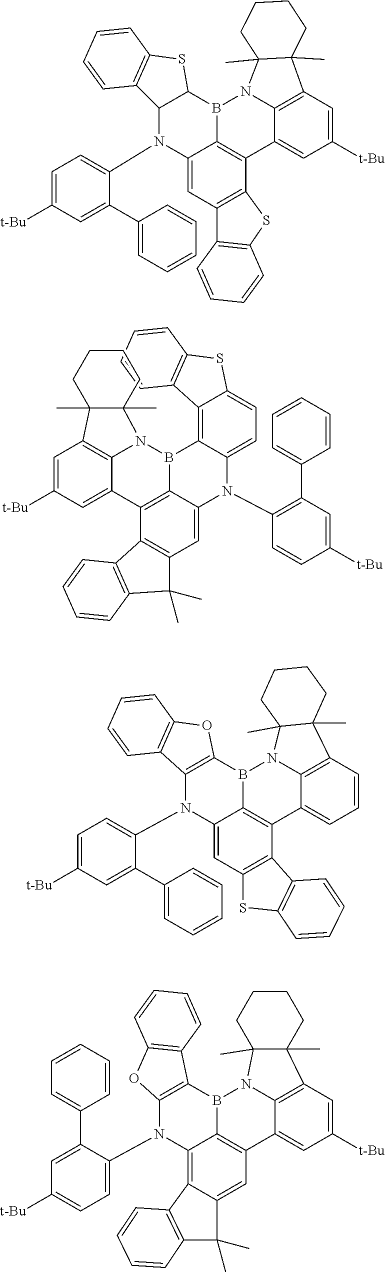 [SMILES: CC(C)(C)c1ccc(N2c3cc4c(sc5ccccc54)c4c3B(C3Sc5ccccc5C32)N2c3c-4cc(C(C)(C)C)cc3C3(C)CCCCC23C)c(-c2ccccc2)c1 ; CC(C)(C)c1ccc(N2c3cc4c(c5c3B(c3c2ccc2sc6ccccc6c32)N2c3c-5cc(C(C)(C)C)cc3C3(C)CCCCC23C)-c2ccccc2C4(C)C)c(-c2ccccc2)c1 ; CC(C)(C)c1ccc(N2c3cc4sc5ccccc5c4c4c3B(c3oc5ccccc5c32)N2c3c-4cccc3C3(C)CCCCC23C)c(-c2ccccc2)c1 ; CC(C)(C)c1ccc(N2c3oc4ccccc4c3B3c4c(cc5c(c42)-c2ccccc2C5(C)C)-c2cc(C(C)(C)C)cc4c2N3C2(C)CCCCC42C)c(-c2ccccc2)c1] 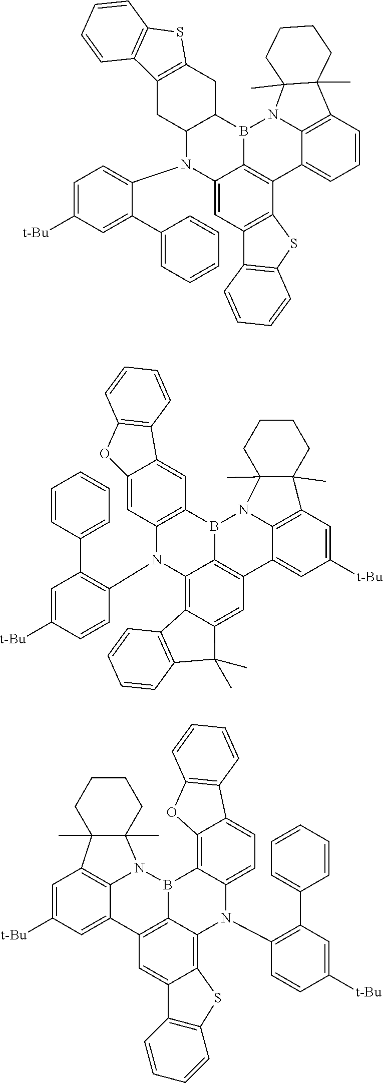 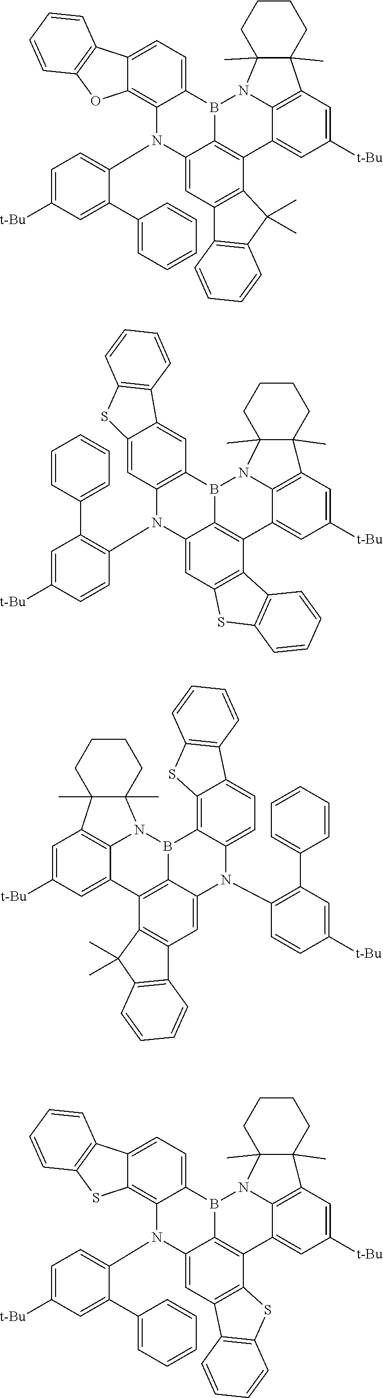 [SMILES: CC(C)(C)c1ccc(N2c3cc4c(c5c3B(c3ccc6c(oc7ccccc76)c32)N2c3c-5cc(C(C)(C)C)cc3C3(C)CCCCC23C)C(C)(C)c2ccccc2-4)c(-c2ccccc2)c1 ; CC(C)(C)c1ccc(N2c3cc4sc5ccccc5c4cc3B3c4c2cc2sc5ccccc5c2c4-c2cc(C(C)(C)C)cc4c2N3C2(C)CCCCC42C)c(-c2ccccc2)c1 ; CC(C)(C)c1ccc(N2c3cc4c(c5c3B(c3c2ccc2c3sc3ccccc32)N2c3c-5cc(C(C)(C)C)cc3C3(C)CCCCC23C)C(C)(C)c2ccccc2-4)c(-c2ccccc2)c1 ; CC(C)(C)c1ccc(N2c3cc4c(sc5ccccc54)c4c3B(c3ccc5c(sc6ccccc65)c32)N2c3c-4cc(C(C)(C)C)cc3C3(C)CCCCC23C)c(-c2ccccc2)c1] 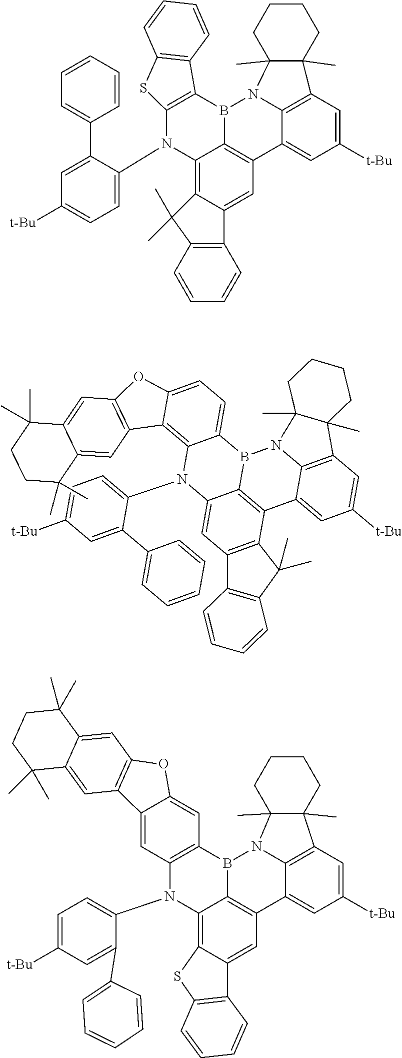 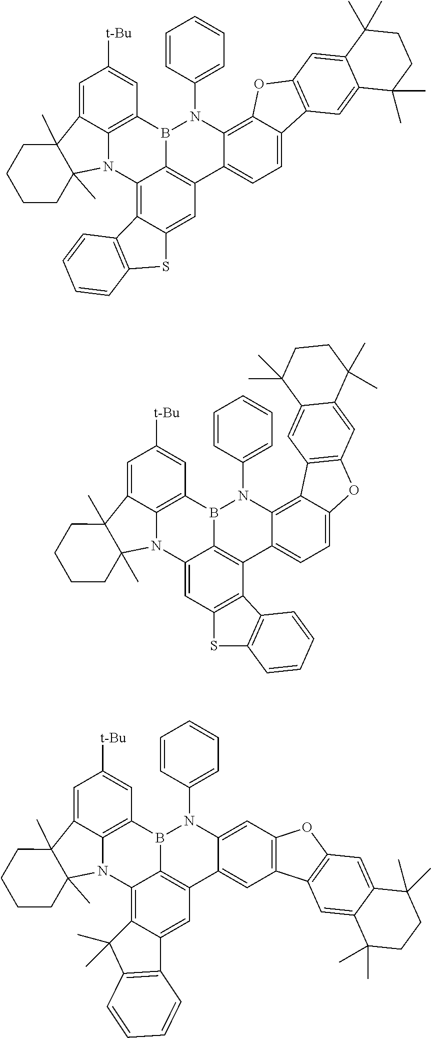 [SMILES: CC(C)(C)c1cc2c3c(c1)C1(C)CCCCC1(C)N3c1c3c(cc4sc5ccccc5c14)-c1ccc4c(oc5cc6c(cc54)C(C)(C)CCC6(C)C)c1N(c1ccccc1)B23 ; CC(C)(C)c1cc2c3c(c1)C1(C)CCCCC1(C)N3c1cc3sc4ccccc4c3c3c1B2N(c1ccccc1)c1c-3ccc2oc3cc4c(cc3c12)C(C)(C)CCC4(C)C ; CC(C)(C)c1cc2c3c(c1)C1(C)CCCCC1(C)N3c1c3c(cc4c1C(C)(C)c1ccccc1-4)-c1cc4c(cc1N(c1ccccc1)B23)oc1cc2c(cc14)C(C)(C)CCC2(C)C] 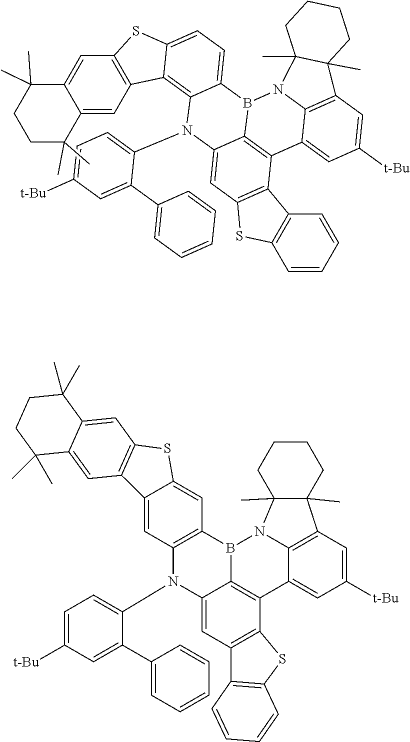 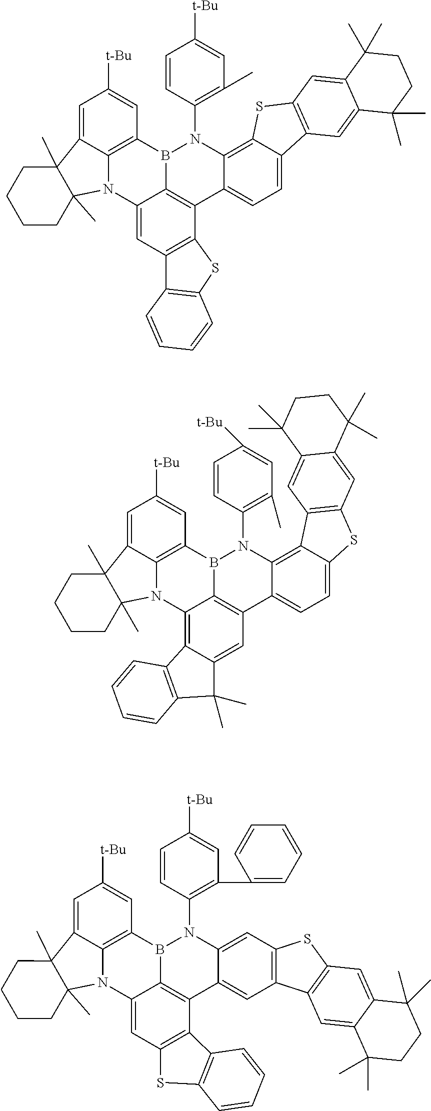 [SMILES: Cc1cc(C(C)(C)C)ccc1N1B2c3cc(C(C)(C)C)cc4c3N(c3cc5c(sc6ccccc65)c(c32)-c2ccc3c(sc5cc6c(cc53)C(C)(C)CCC6(C)C)c21)C1(C)CCCCC41C ; Cc1cc(C(C)(C)C)ccc1N1B2c3cc(C(C)(C)C)cc4c3N(c3c2c(cc2c3-c3ccccc3C2(C)C)-c2ccc3sc5cc6c(cc5c3c21)C(C)(C)CCC6(C)C)C1(C)CCCCC41C ; CC(C)(C)c1ccc(N2B3c4cc(C(C)(C)C)cc5c4N(c4cc6sc7ccccc7c6c(c43)-c3cc4c(cc32)sc2cc3c(cc24)C(C)(C)CCC3(C)C)C2(C)CCCCC52C)c(-c2ccccc2)c1] 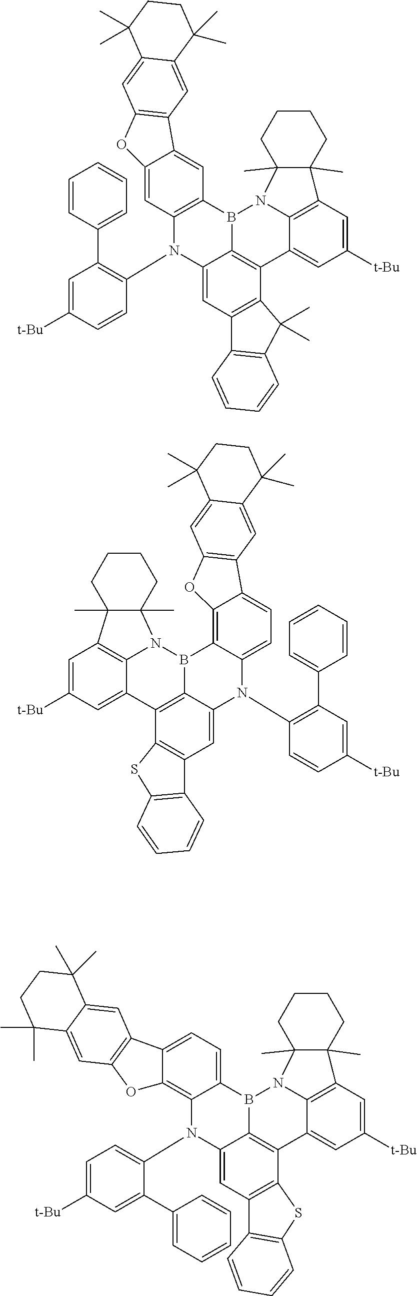 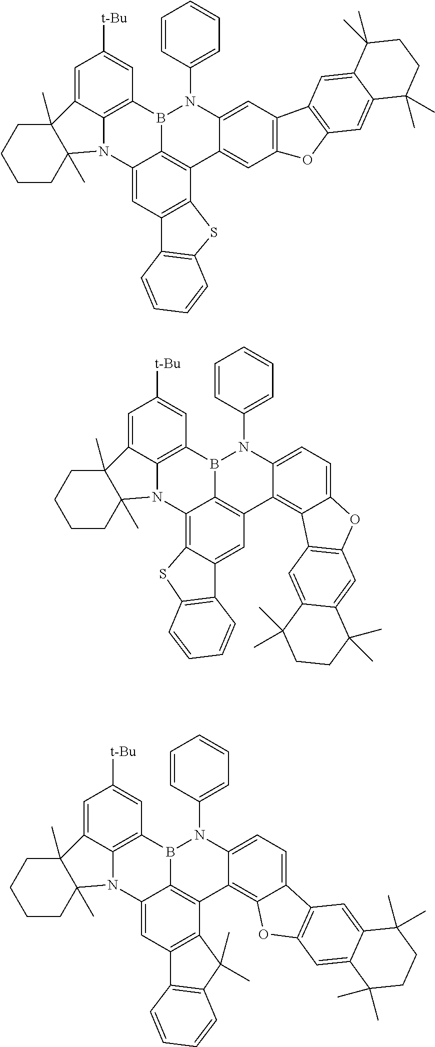 [SMILES: CC(C)(C)c1cc2c3c(c1)C1(C)CCCCC1(C)N3c1cc3c(sc4ccccc43)c3c1B2N(c1ccccc1)c1cc2c(cc1-3)oc1cc3c(cc12)C(C)(C)CCC3(C)C ; CC(C)(C)c1cc2c3c(c1)C1(C)CCCCC1(C)N3c1c3c(cc4c1sc1ccccc14)-c1c(ccc4oc5cc6c(cc5c14)C(C)(C)CCC6(C)C)N(c1ccccc1)B23 ; CC(C)(C)c1cc2c3c(c1)C1(C)CCCCC1(C)N3c1cc3c(c4c1B2N(c1ccccc1)c1ccc2c(oc5cc6c(cc52)C(C)(C)CCC6(C)C)c1-4)C(C)(C)c1ccccc1-3] 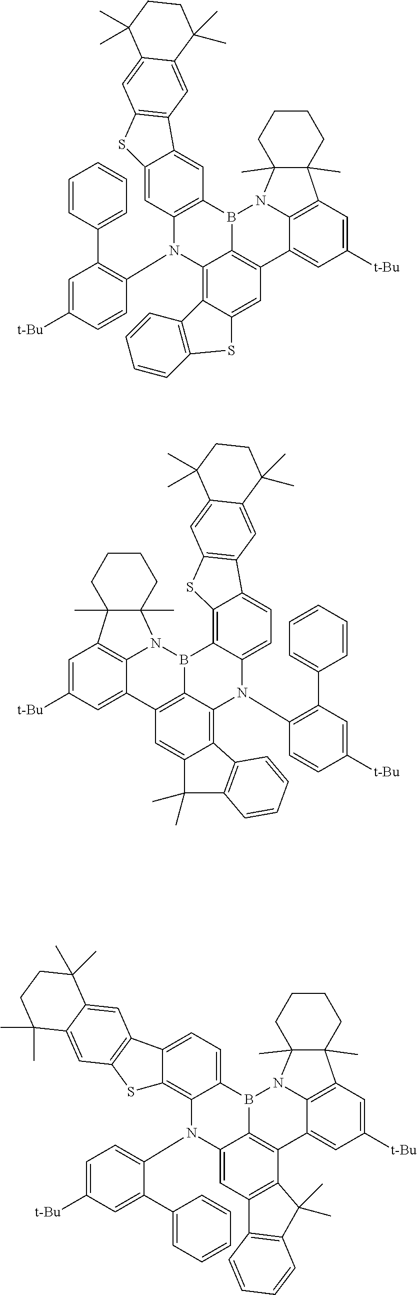 [SMILES: CC(C)(C)c1ccc(N2c3cc4sc5cc6c(cc5c4cc3B3c4c(cc5sc7ccccc7c5c42)-c2cc(C(C)(C)C)cc4c2N3C2(C)CCCCC42C)C(C)(C)CCC6(C)C)c(-c2ccccc2)c1 ; CC(C)(C)c1ccc(N2c3ccc4c(sc5cc6c(cc54)C(C)(C)CCC6(C)C)c3B3c4c(cc5c(c42)-c2ccccc2C5(C)C)-c2cc(C(C)(C)C)cc4c2N3C2(C)CCCCC42C)c(-c2ccccc2)c1 ; CC(C)(C)c1ccc(N2c3cc4c(c5c3B(c3ccc6c(sc7cc8c(cc76)C(C)(C)CCC8(C)C)c32)N2c3c-5cc(C(C)(C)C)cc3C3(C)CCCCC23C)C(C)(C)c2ccccc2-4)c(-c2ccccc2)c1] 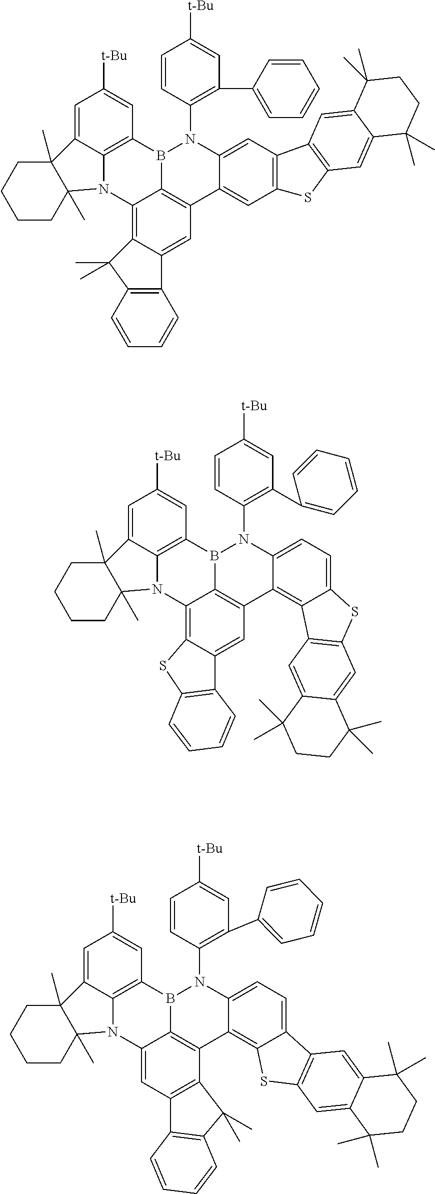 [SMILES: CC(C)(C)c1ccc(N2B3c4cc(C(C)(C)C)cc5c4N(c4c3c(cc3c4C(C)(C)c4ccccc4-3)-c3cc4sc6cc7c(cc6c4cc32)C(C)(C)CCC7(C)C)C2(C)CCCCC52C)c(-c2ccccc2)c1 ; CC(C)(C)c1ccc(N2B3c4cc(C(C)(C)C)cc5c4N(c4c3c(cc3c4sc4ccccc43)-c3c2ccc2sc4cc6c(cc4c32)C(C)(C)CCC6(C)C)C2(C)CCCCC52C)c(-c2ccccc2)c1 ; CC(C)(C)c1ccc(N2B3c4cc(C(C)(C)C)cc5c4N(c4cc6c(c(c43)-c3c2ccc2c3sc3cc4c(cc32)C(C)(C)CCC4(C)C)C(C)(C)c2ccccc2-6)C2(C)CCCCC52C)c(-c2ccccc2)c1] 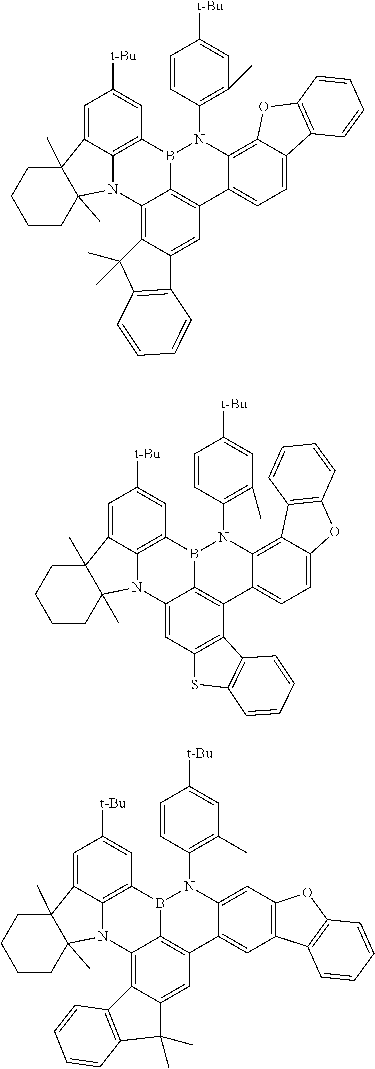 [SMILES: Cc1cc(C(C)(C)C)ccc1N1B2c3cc(C(C)(C)C)cc4c3N(c3c2c(cc2c3C(C)(C)c3ccccc3-2)-c2ccc3c(oc5ccccc53)c21)C1(C)CCCCC41C ; Cc1cc(C(C)(C)C)ccc1N1B2c3cc(C(C)(C)C)cc4c3N(c3cc5sc6ccccc6c5c(c32)-c2ccc3oc5ccccc5c3c21)C1(C)CCCCC41C ; Cc1cc(C(C)(C)C)ccc1N1B2c3cc(C(C)(C)C)cc4c3N(c3c2c(cc2c3-c3ccccc3C2(C)C)-c2cc3c(cc21)oc1ccccc13)C1(C)CCCCC41C] 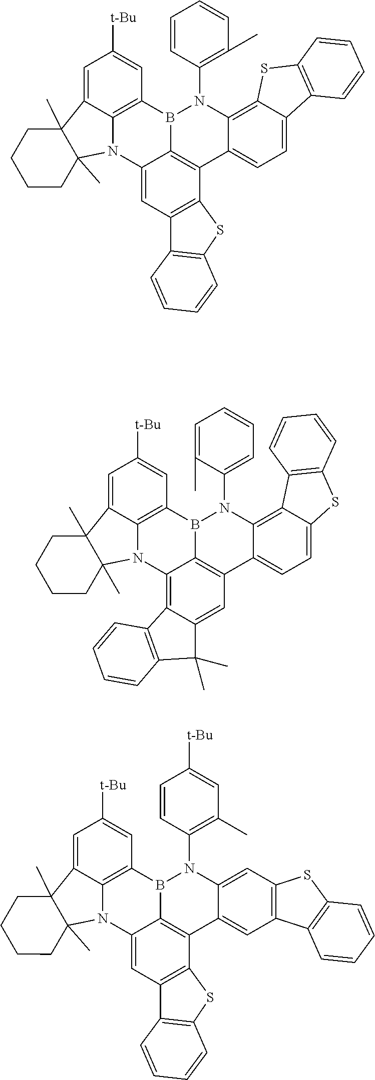 [SMILES: Cc1ccccc1N1B2c3cc(C(C)(C)C)cc4c3N(c3cc5c(sc6ccccc65)c(c32)-c2ccc3c(sc5ccccc53)c21)C1(C)CCCCC41C ; Cc1ccccc1N1B2c3cc(C(C)(C)C)cc4c3N(c3c2c(cc2c3-c3ccccc3C2(C)C)-c2ccc3sc5ccccc5c3c21)C1(C)CCCCC41C ; CSc1ccccc1-c1cc2c3c(c1)N1c4c(cc(C(C)(C)C)cc4C4(C)CCCCC14C)B3N(c1ccc(C(C)(C)C)cc1C)c1cc3sc4ccccc4c3cc1-2] 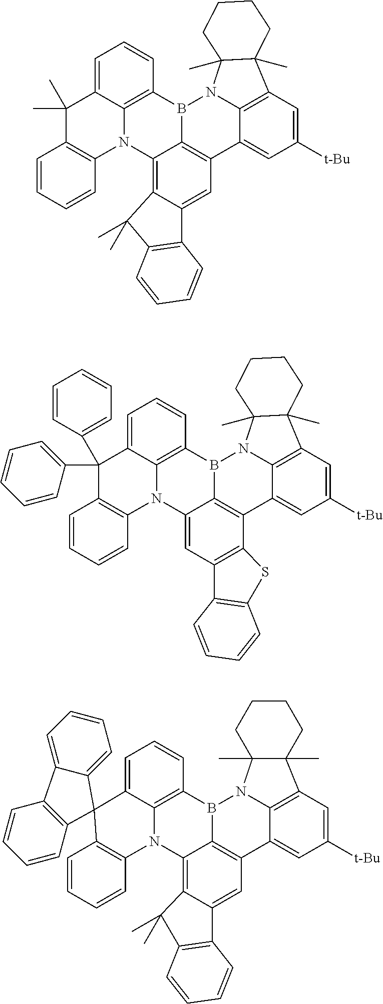 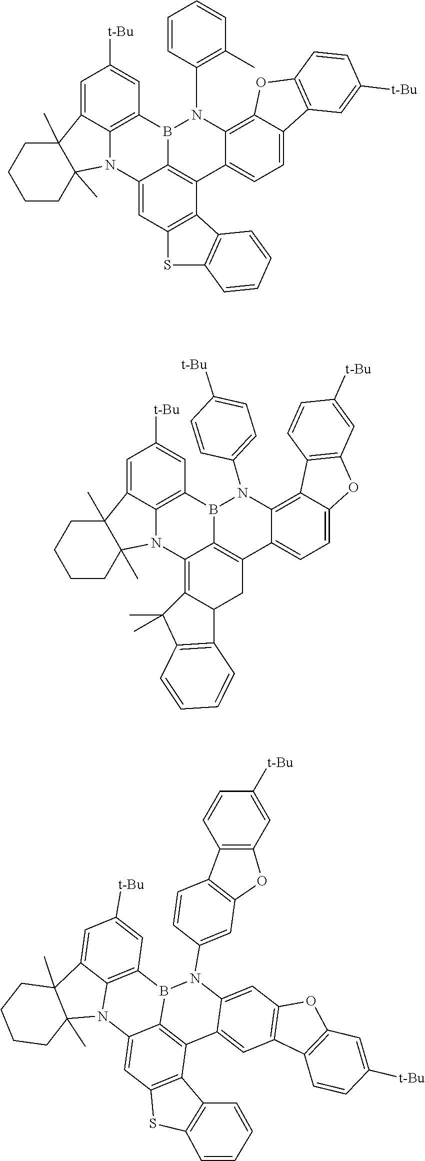 [SMILES: Cc1ccccc1N1B2c3cc(C(C)(C)C)cc4c3N(c3cc5sc6ccccc6c5c(c32)-c2ccc3c(oc5ccc(C(C)(C)C)cc53)c21)C1(C)CCCCC41C ; CC(C)(C)c1ccc(N2B3C4=C(CC5C(=C4N4c6c3cc(C(C)(C)C)cc6C3(C)CCCCC43C)C(C)(C)c3ccccc35)c3ccc4oc5cc(C(C)(C)C)ccc5c4c32)cc1 ; CC(C)(C)c1cc2c3c(c1)C1(C)CCCCC1(C)N3c1cc3sc4ccccc4c3c3c1B2N(c1ccc2c(c1)oc1cc(C(C)(C)C)ccc12)c1cc2oc4cc(C(C)(C)C)ccc4c2cc1-3] 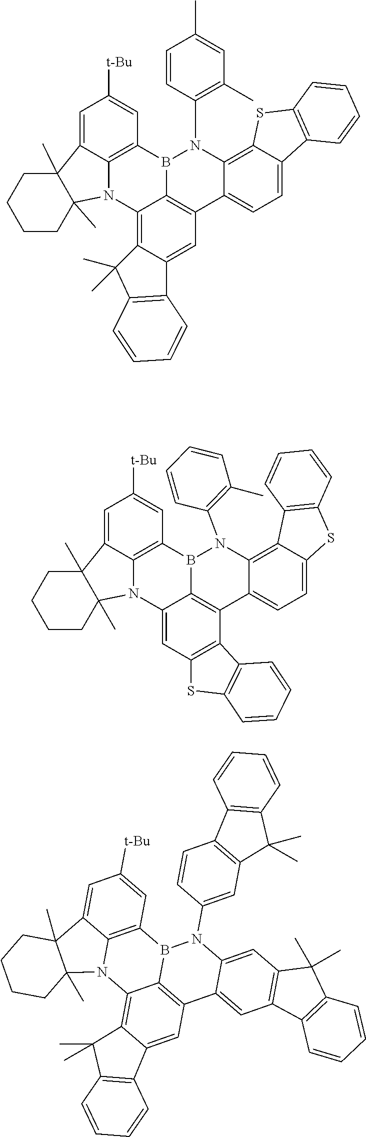 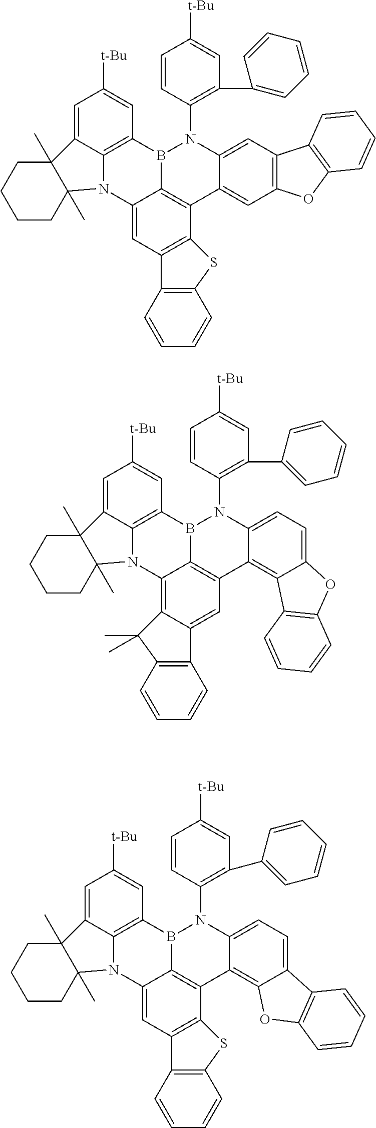 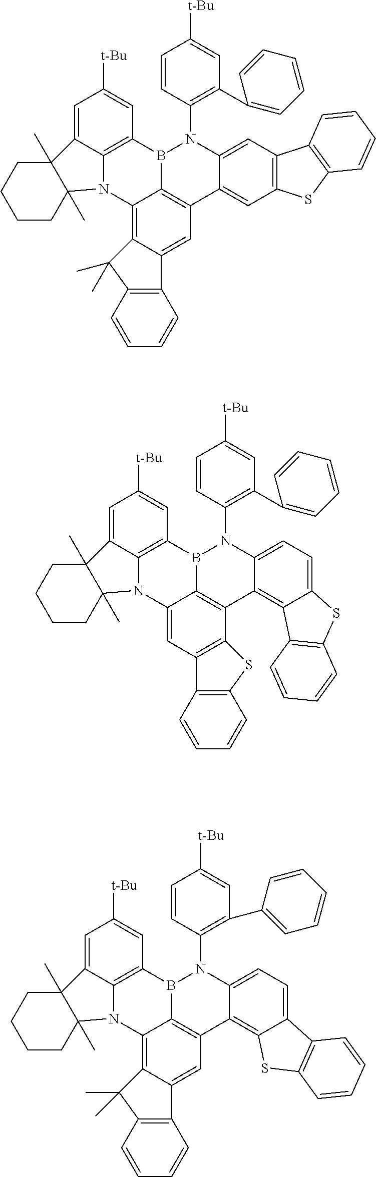 [SMILES: CC(C)(C)c1ccc(N2B3c4cc(C(C)(C)C)cc5c4N(c4c3c(cc3c4C(C)(C)c4ccccc4-3)-c3cc4sc6ccccc6c4cc32)C2(C)CCCCC52C)c(-c2ccccc2)c1 ; CC(C)(C)c1ccc(N2B3c4cc(C(C)(C)C)cc5c4N(c4cc6c(sc7ccccc76)c(c43)-c3c2ccc2sc4ccccc4c32)C2(C)CCCCC52C)c(-c2ccccc2)c1 ; CC(C)(C)c1ccc(N2B3c4cc(C(C)(C)C)cc5c4N(c4c3c(cc3c4C(C)(C)c4ccccc4-3)-c3c2ccc2c3sc3ccccc32)C2(C)CCCCC52C)c(-c2ccccc2)c1] 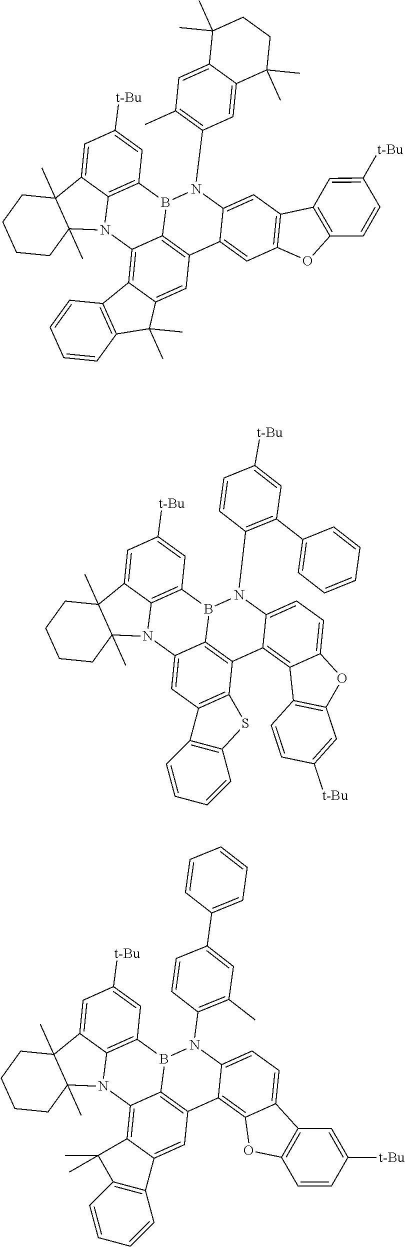 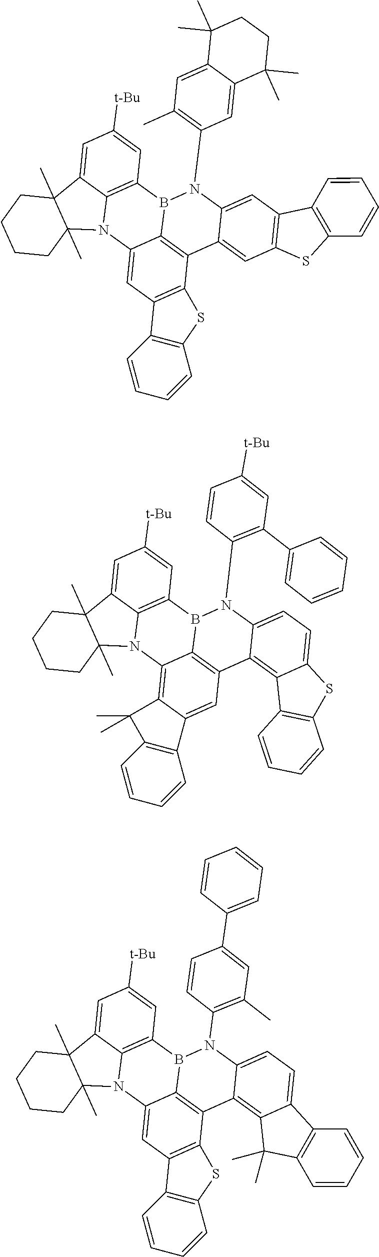 [SMILES: Cc1cc2c(cc1N1B3c4cc(C(C)(C)C)cc5c4N(c4cc6c(sc7ccccc76)c(c43)-c3cc4sc6ccccc6c4cc31)C1(C)CCCCC51C)C(C)(C)CCC2(C)C ; CC(C)(C)c1ccc(N2B3c4cc(C(C)(C)C)cc5c4N(c4c3c(cc3c4C(C)(C)c4ccccc4-3)-c3c2ccc2sc4ccccc4c32)C2(C)CCCCC52C)c(-c2ccccc2)c1 ; Cc1cc(-c2ccccc2)ccc1N1B2c3cc(C(C)(C)C)cc4c3N(c3cc5c(sc6ccccc65)c(c32)-c2c1ccc1c2C(C)(C)c2ccccc2-1)C1(C)CCCCC41C] 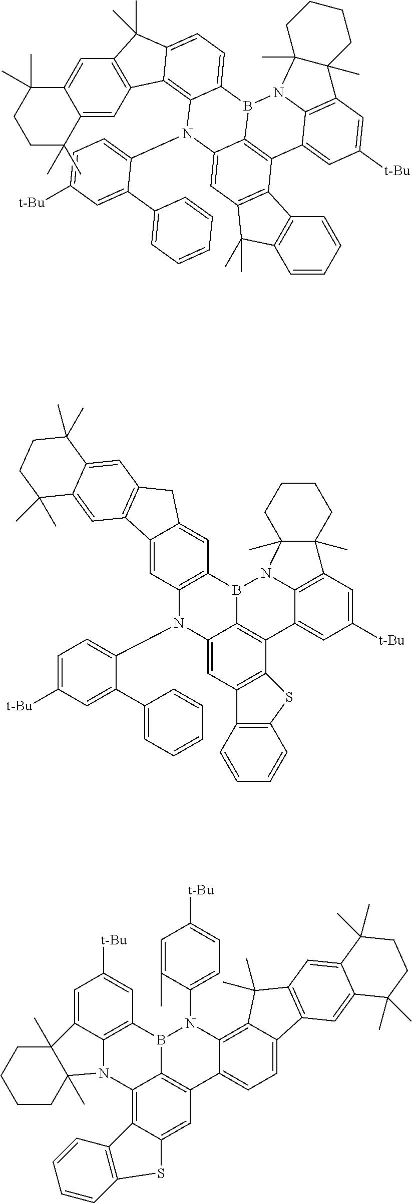 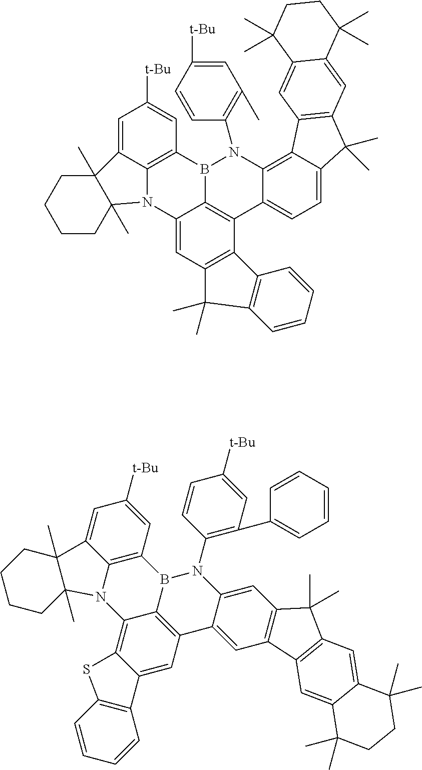 [SMILES: Cc1cc(C(C)(C)C)ccc1N1B2c3cc(C(C)(C)C)cc4c3N(c3cc5c(c(c32)-c2ccc3c(c21)-c1cc2c(cc1C3(C)C)C(C)(C)CCC2(C)C)-c1ccccc1C5(C)C)C1(C)CCCCC41C ; CC(C)(C)c1ccc(N2B3c4cc(C(C)(C)C)cc5c4N(c4c3c(cc3c4sc4ccccc43)-c3cc4c(cc32)C(C)(C)c2cc3c(cc2-4)C(C)(C)CCC3(C)C)C2(C)CCCCC52C)c(-c2ccccc2)c1] 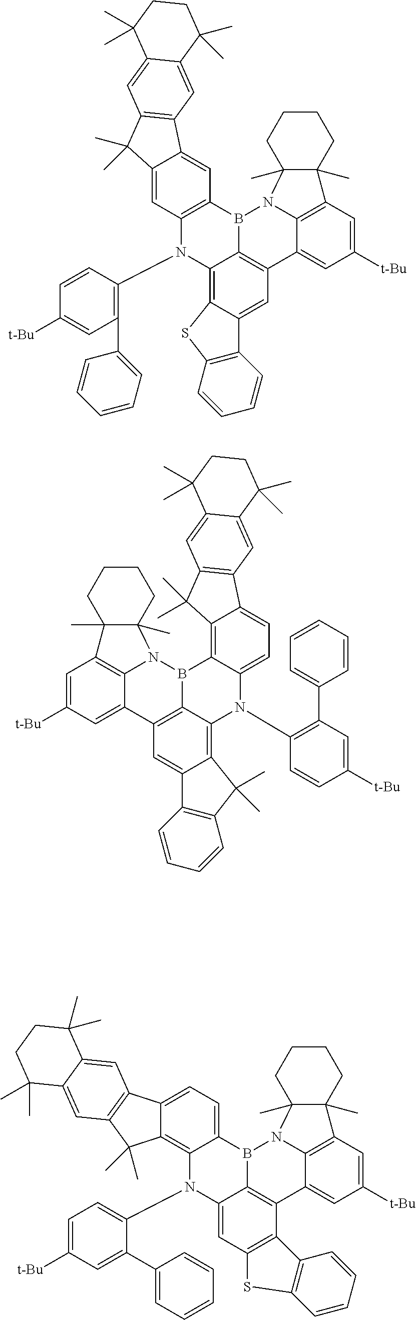 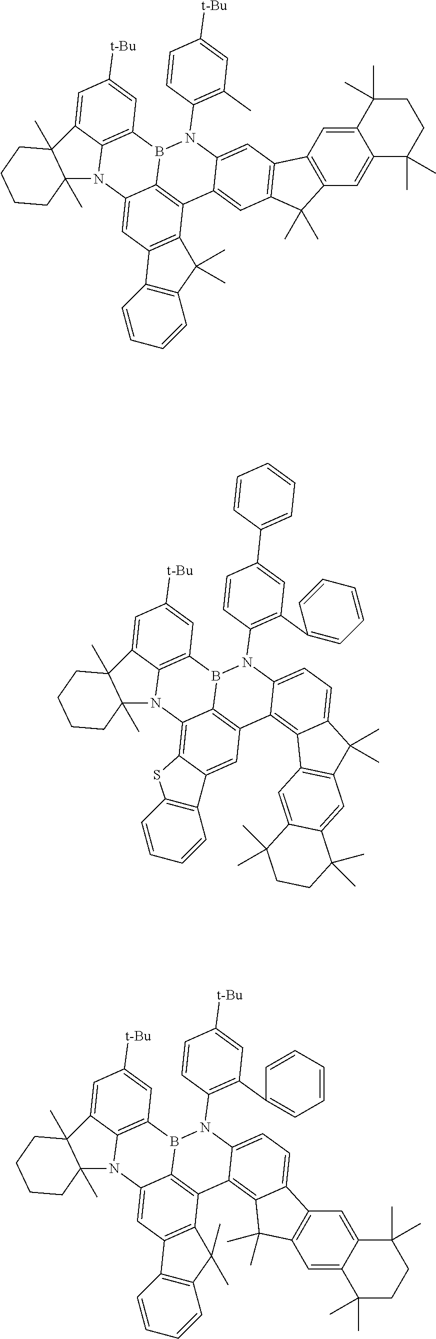 [SMILES: Cc1cc(C(C)(C)C)ccc1N1B2c3cc(C(C)(C)C)cc4c3N(c3cc5c(c(c32)-c2cc3c(cc21)-c1cc2c(cc1C3(C)C)C(C)(C)CCC2(C)C)C(C)(C)c1ccccc1-5)C1(C)CCCCC41C ; CC(C)(C)c1cc2c3c(c1)C1(C)CCCCC1(C)N3c1c3c(cc4c1sc1ccccc14)-c1c(ccc4c1-c1cc5c(cc1C4(C)C)C(C)(C)CCC5(C)C)N(c1ccc(-c4ccccc4)cc1-c1ccccc1)B23 ; CC(C)(C)c1ccc(N2B3c4cc(C(C)(C)C)cc5c4N(c4cc6c(c(c43)-c3c2ccc2c3C(C)(C)c3cc4c(cc3-2)C(C)(C)CCC4(C)C)C(C)(C)c2ccccc2-6)C2(C)CCCCC52C)c(-c2ccccc2)c1] 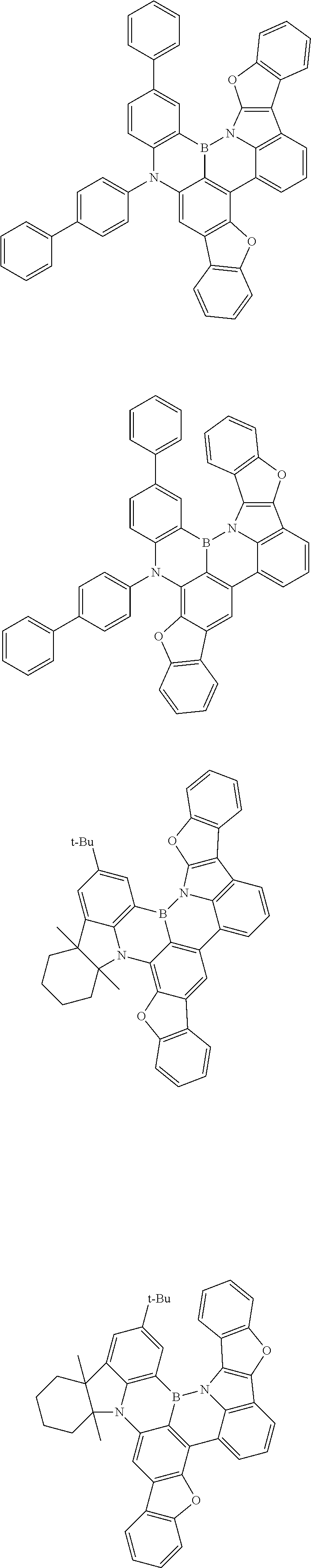 [SMILES: c1ccc(-c2ccc(N3c4ccc(-c5ccccc5)cc4B4c5c3cc3c(oc6ccccc63)c5-c3cccc5c6c7ccccc7oc6n4c35)cc2)cc1 ; c1ccc(-c2ccc(N3c4ccc(-c5ccccc5)cc4B4c5c(cc6c(oc7ccccc76)c53)-c3cccc5c6oc7ccccc7c6n4c35)cc2)cc1 ; CC(C)(C)c1cc2c3c(c1)C1(C)CCCCC1(C)N3c1c3c(cc4c1oc1ccccc14)-c1cccc4c5c6ccccc6oc5n(c14)B23 ; CC(C)(C)c1cc2c3c(c1)C1(C)CCCCC1(C)N3c1cc3c(oc4ccccc43)c3c1B2n1c2c-3cccc2c2oc3ccccc3c21] 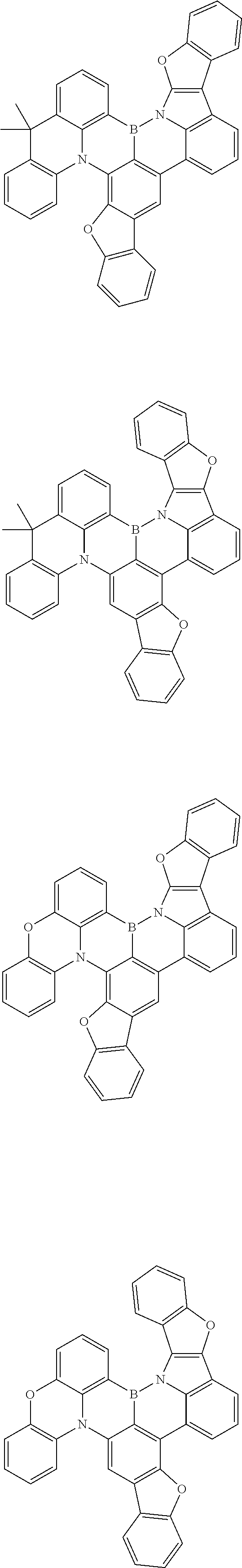 [SMILES: CC1(C)c2ccccc2N2c3c(cccc31)B1c3c(cc4c(oc5ccccc54)c32)-c2cccc3c4c5ccccc5oc4n1c23 ; CC1(C)c2ccccc2N2c3cc4c(oc5ccccc54)c4c3B(c3cccc1c32)n1c2c-4cccc2c2oc3ccccc3c21 ; c1ccc2c(c1)Oc1cccc3c1N2c1c2c(cc4c1oc1ccccc14)-c1cccc4c5c6ccccc6oc5n(c14)B32 ; c1ccc2c(c1)Oc1cccc3c1N2c1cc2c(oc4ccccc42)c2c1B3n1c3c-2cccc3c2oc3ccccc3c21] 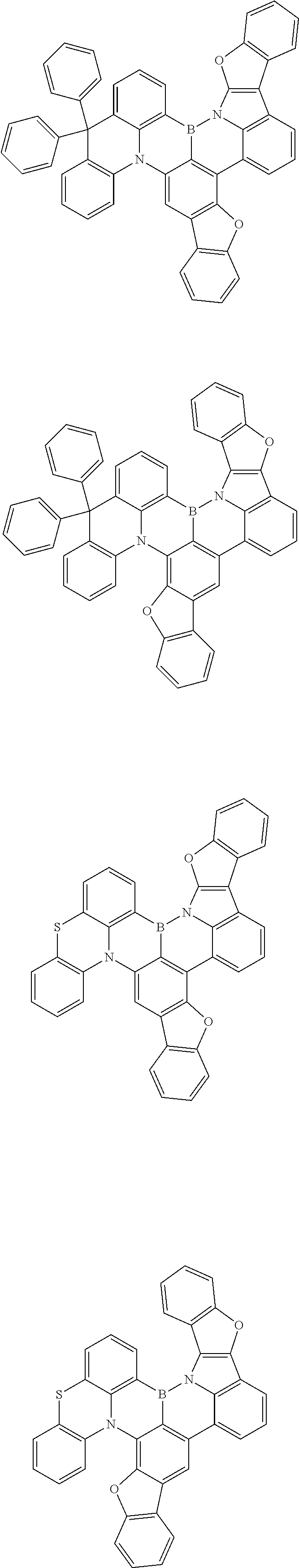 [SMILES: c1ccc(C2(c3ccccc3)c3ccccc3N3c4cc5c(oc6ccccc65)c5c4B(c4cccc2c43)n2c3oc4ccccc4c3c3cccc-5c32)cc1 ; c1ccc(C2(c3ccccc3)c3ccccc3N3c4c(cccc42)B2c4c(cc5c(oc6ccccc65)c43)-c3cccc4c5oc6ccccc6c5n2c34)cc1 ; c1ccc2c(c1)Sc1cccc3c1N2c1cc2c(oc4ccccc42)c2c1B3n1c3oc4ccccc4c3c3cccc-2c31 ; c1ccc2c(c1)Sc1cccc3c1N2c1c2c(cc4c1oc1ccccc14)-c1cccc4c5oc6ccccc6c5n(c14)B32] 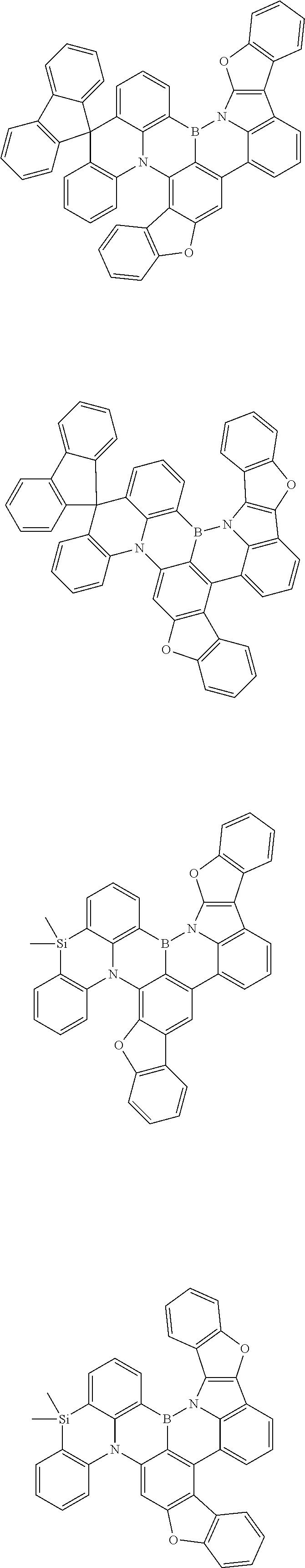 [SMILES: c1ccc2c(c1)-c1ccccc1C21c2ccccc2N2c3c(cccc31)B1c3c(cc4oc5ccccc5c4c32)-c2cccc3c4c5ccccc5oc4n1c23 ; c1ccc2c(c1)-c1ccccc1C21c2ccccc2N2c3cc4oc5ccccc5c4c4c3B(c3cccc1c32)n1c2c-4cccc2c2oc3ccccc3c21 ; C[Si]1(C)c2ccccc2N2c3c(cccc31)B1c3c(cc4c(oc5ccccc54)c32)-c2cccc3c4c5ccccc5oc4n1c23 ; C[Si]1(C)c2ccccc2N2c3cc4oc5ccccc5c4c4c3B(c3cccc1c32)n1c2c-4cccc2c2oc3ccccc3c21] 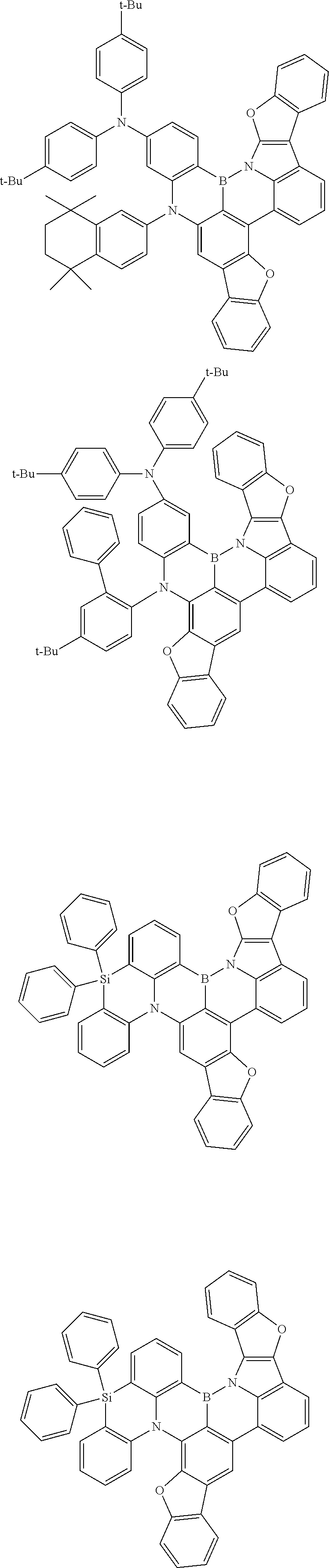 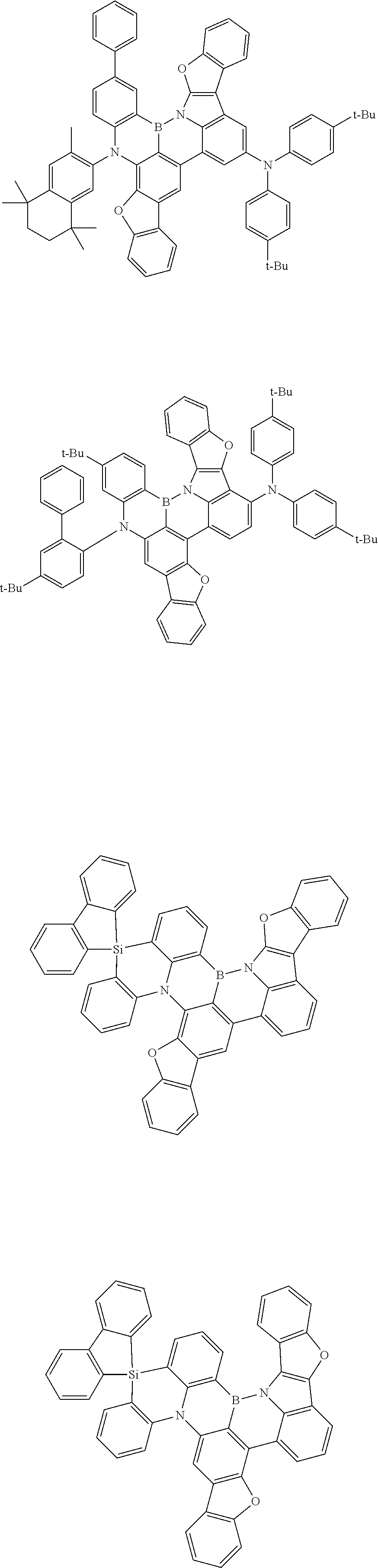 [SMILES: Cc1cc2c(cc1N1c3ccc(-c4ccccc4)cc3B3c4c(cc5c(oc6ccccc65)c41)-c1cc(N(c4ccc(C(C)(C)C)cc4)c4ccc(C(C)(C)C)cc4)cc4c5c6ccccc6oc5n3c14)C(C)(C)CCC2(C)C ; CC(C)(C)c1ccc(N(c2ccc(C(C)(C)C)cc2)c2ccc3c4c2c2oc5ccccc5c2n4B2c4ccc(C(C)(C)C)cc4N(c4ccc(C(C)(C)C)cc4-c4ccccc4)c4cc5c(oc6ccccc65)c-3c42)cc1 ; c1ccc2c(c1)-c1ccccc1[Si]21c2ccccc2N2c3c(cccc31)B1c3c(cc4c(oc5ccccc54)c32)-c2cccc3c4c5ccccc5oc4n1c23 ; c1ccc2c(c1)-c1ccccc1[Si]21c2ccccc2N2c3cc4c(oc5ccccc54)c4c3B(c3cccc1c32)n1c2c-4cccc2c2oc3ccccc3c21] 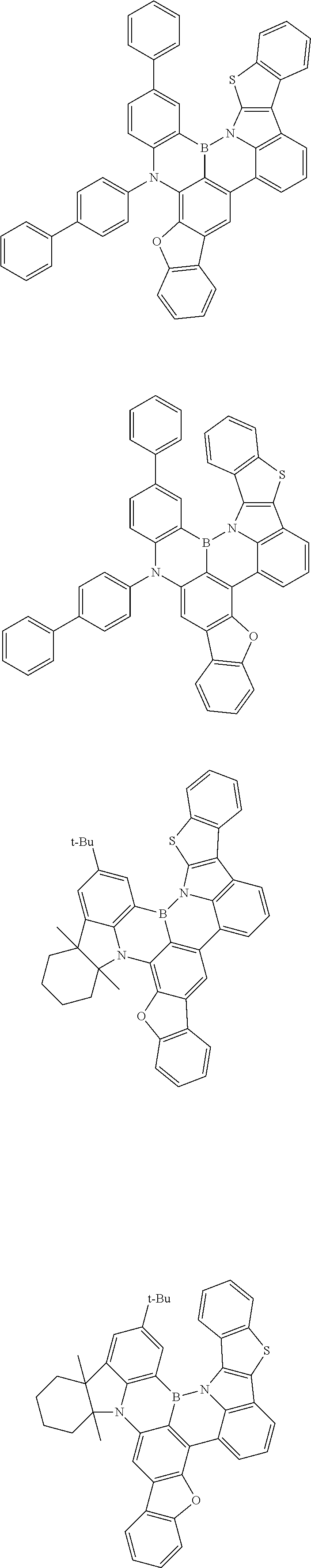 [SMILES: c1ccc(-c2ccc(N3c4ccc(-c5ccccc5)cc4B4c5c(cc6c(oc7ccccc76)c53)-c3cccc5c6c7ccccc7sc6n4c35)cc2)cc1 ; c1ccc(-c2ccc(N3c4ccc(-c5ccccc5)cc4B4c5c3cc3c(oc6ccccc63)c5-c3cccc5c6sc7ccccc7c6n4c35)cc2)cc1 ; CC(C)(C)c1cc2c3c(c1)C1(C)CCCCC1(C)N3c1c3c(cc4c1oc1ccccc14)-c1cccc4c5c6ccccc6sc5n(c14)B23 ; CC(C)(C)c1cc2c3c(c1)C1(C)CCCCC1(C)N3c1cc3c(oc4ccccc43)c3c1B2n1c2c-3cccc2c2sc3ccccc3c21] 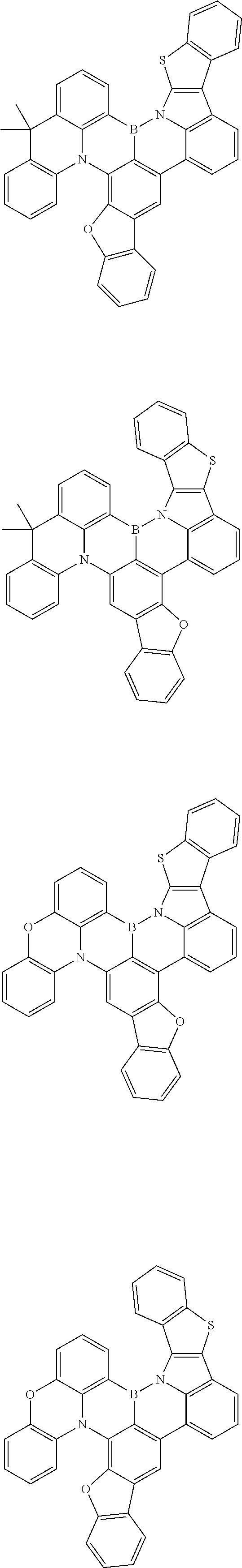 [SMILES: CC1(C)c2ccccc2N2c3c(cccc31)B1c3c(cc4c(oc5ccccc54)c32)-c2cccc3c4c5ccccc5sc4n1c23 ; CC1(C)c2ccccc2N2c3cc4c(oc5ccccc54)c4c3B(c3cccc1c32)n1c2c-4cccc2c2sc3ccccc3c21 ; c1ccc2c(c1)Oc1cccc3c1N2c1cc2c(oc4ccccc42)c2c1B3n1c3sc4ccccc4c3c3cccc-2c31 ; c1ccc2c(c1)Oc1cccc3c1N2c1c2c(cc4c1oc1ccccc14)-c1cccc4c5sc6ccccc6c5n(c14)B32] 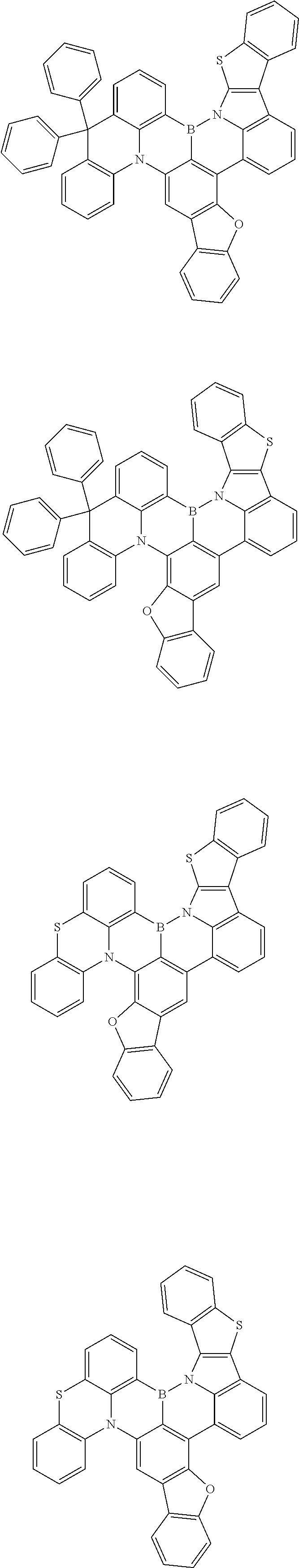 [SMILES: c1ccc(C2(c3ccccc3)c3ccccc3N3c4cc5c(oc6ccccc65)c5c4B(c4cccc2c43)n2c3sc4ccccc4c3c3cccc-5c32)cc1 ; c1ccc(C2(c3ccccc3)c3ccccc3N3c4c(cccc42)B2c4c(cc5c(oc6ccccc65)c43)-c3cccc4c5sc6ccccc6c5n2c34)cc1 ; c1ccc2c(c1)Sc1cccc3c1N2c1c2c(cc4c1oc1ccccc14)-c1cccc4c5c6ccccc6sc5n(c14)B32 ; c1ccc2c(c1)Sc1cccc3c1N2c1cc2c(oc4ccccc42)c2c1B3n1c3c-2cccc3c2sc3ccccc3c21] 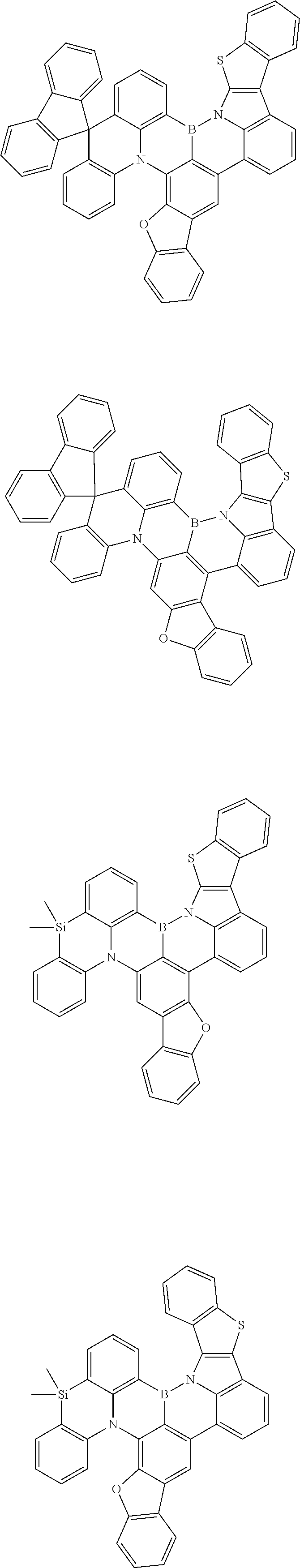 [SMILES: c1ccc2c(c1)-c1ccccc1C21c2ccccc2N2c3c(cccc31)B1c3c(cc4c(oc5ccccc54)c32)-c2cccc3c4c5ccccc5sc4n1c23 ; c1ccc2c(c1)-c1ccccc1C21c2ccccc2N2c3cc4oc5ccccc5c4c4c3B(c3cccc1c32)n1c2c-4cccc2c2sc3ccccc3c21 ; C[Si]1(C)c2ccccc2N2c3cc4c(oc5ccccc54)c4c3B(c3cccc1c32)n1c2sc3ccccc3c2c2cccc-4c21 ; C[Si]1(C)c2ccccc2N2c3c(cccc31)B1c3c(cc4c(oc5ccccc54)c32)-c2cccc3c4sc5ccccc5c4n1c23] 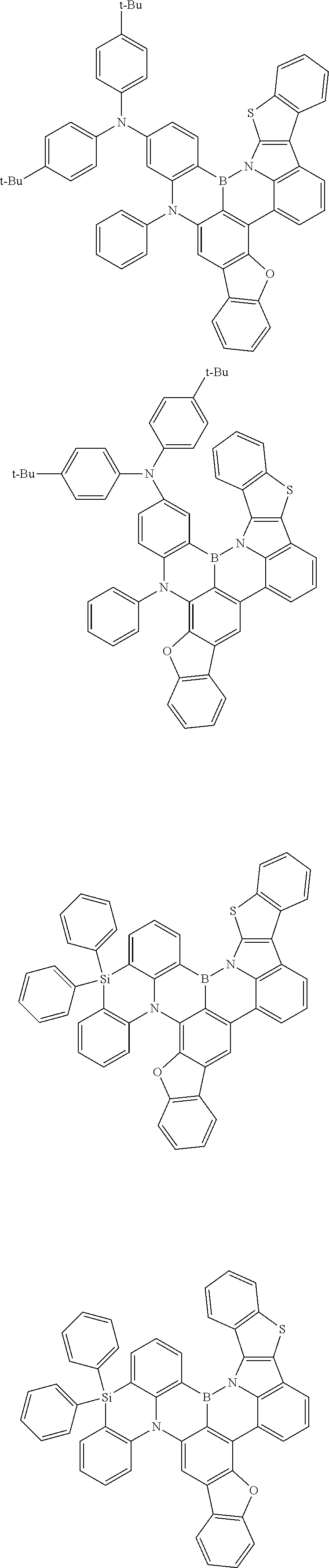 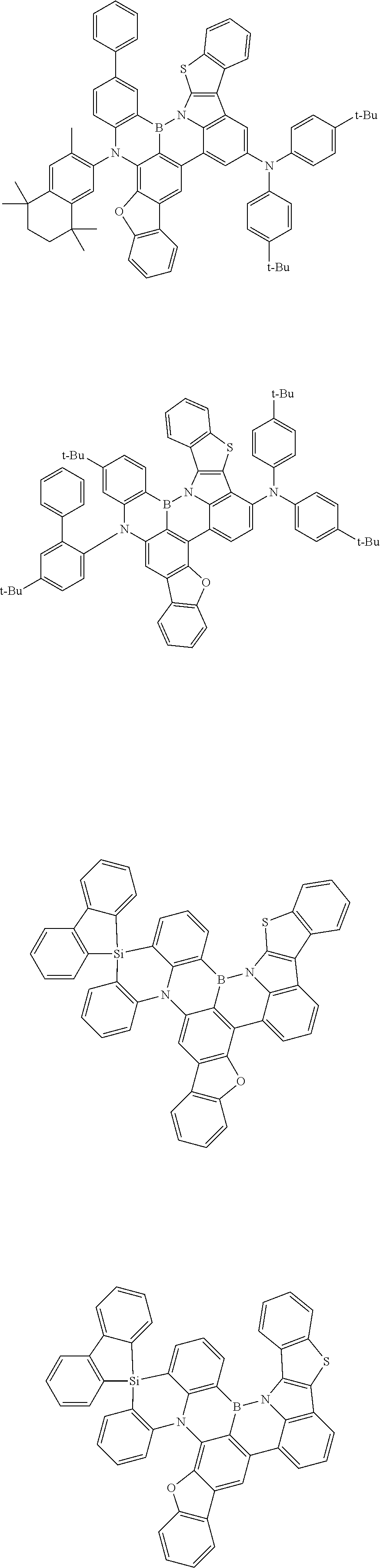 [SMILES: Cc1cc2c(cc1N1c3ccc(-c4ccccc4)cc3B3c4c(cc5c(oc6ccccc65)c41)-c1cc(N(c4ccc(C(C)(C)C)cc4)c4ccc(C(C)(C)C)cc4)cc4c5c6ccccc6sc5n3c14)C(C)(C)CCC2(C)C ; CC(C)(C)c1ccc(N(c2ccc(C(C)(C)C)cc2)c2ccc3c4c2c2sc5ccccc5c2n4B2c4ccc(C(C)(C)C)cc4N(c4ccc(C(C)(C)C)cc4-c4ccccc4)c4cc5c(oc6ccccc65)c-3c42)cc1 ; c1ccc2c(c1)-c1ccccc1[Si]21c2ccccc2N2c3cc4c(oc5ccccc54)c4c3B(c3cccc1c32)n1c2sc3ccccc3c2c2cccc-4c21 ; c1ccc2c(c1)-c1ccccc1[Si]21c2ccccc2N2c3c(cccc31)B1c3c(cc4c(oc5ccccc54)c32)-c2cccc3c4sc5ccccc5c4n1c23] 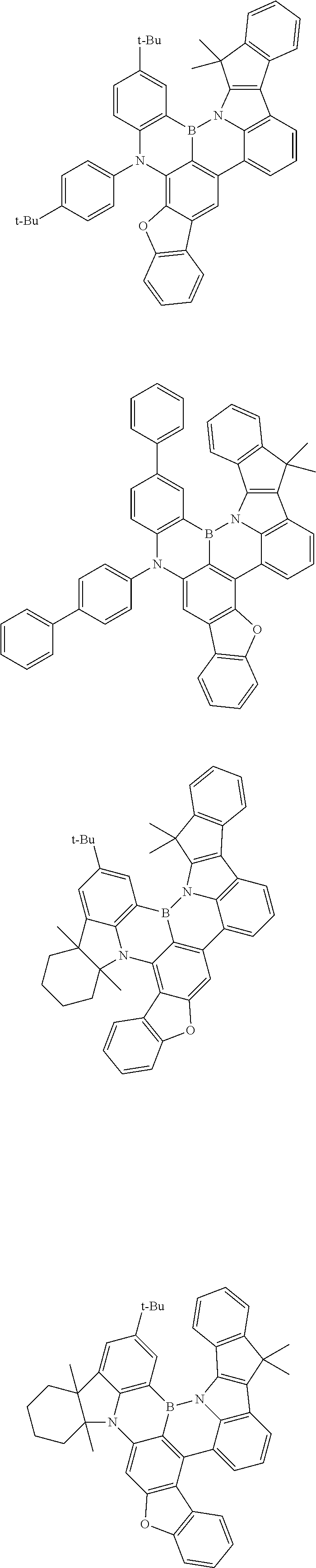 [SMILES: CC(C)(C)c1ccc(N2c3ccc(C(C)(C)C)cc3B3c4c(cc5c(oc6ccccc65)c42)-c2cccc4c5c(n3c24)C(C)(C)c2ccccc2-5)cc1 ; CC1(C)c2ccccc2-c2c1c1cccc3c1n2B1c2cc(-c4ccccc4)ccc2N(c2ccc(-c4ccccc4)cc2)c2cc4c(oc5ccccc54)c-3c21 ; CC(C)(C)c1cc2c3c(c1)C1(C)CCCCC1(C)N3c1c3c(cc4oc5ccccc5c14)-c1cccc4c5c(n(c14)B23)C(C)(C)c1ccccc1-5 ; CC(C)(C)c1cc2c3c(c1)C1(C)CCCCC1(C)N3c1cc3oc4ccccc4c3c3c1B2n1c2c(c4cccc-3c41)C(C)(C)c1ccccc1-2] 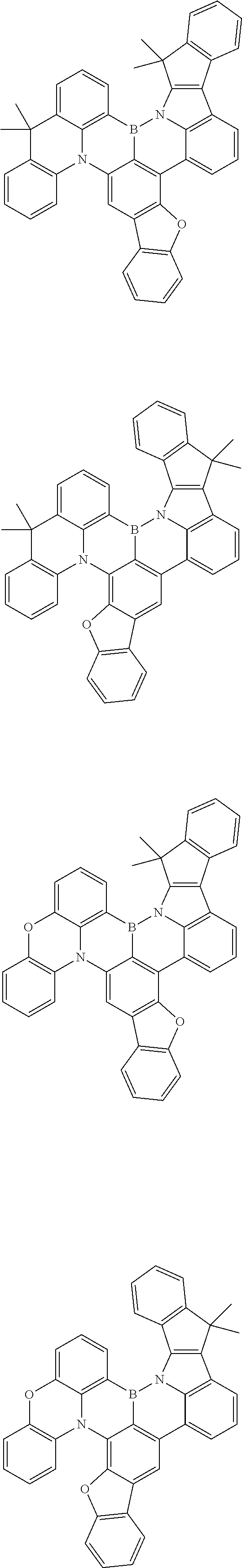 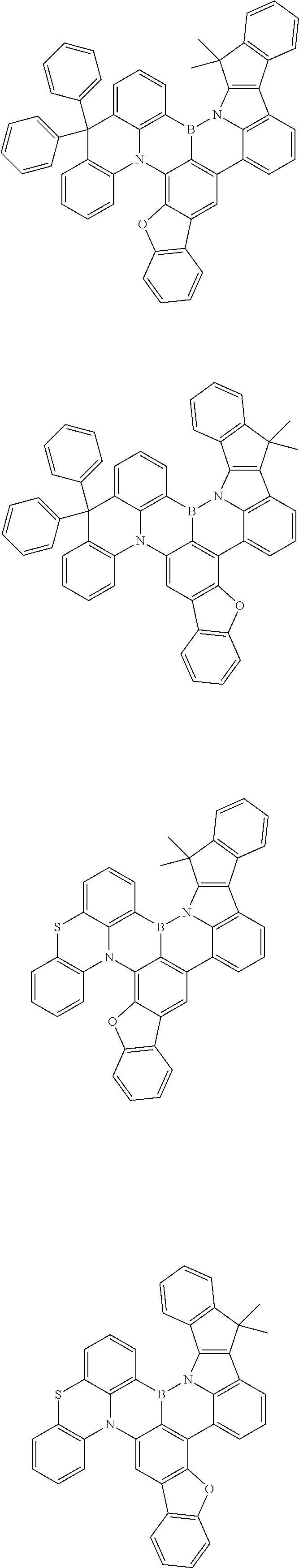 [SMILES: CC1(C)c2ccccc2-c2c1n1c3c(cccc23)-c2cc3c(oc4ccccc43)c3c2B1c1cccc2c1N3c1ccccc1C2(c1ccccc1)c1ccccc1 ; CC1(C)c2ccccc2-c2c1c1cccc3c1n2B1c2cccc4c2N(c2ccccc2C4(c2ccccc2)c2ccccc2)c2cc4c(oc5ccccc54)c-3c21 ; CC1(C)c2ccccc2-c2c1n1c3c(cccc23)-c2cc3c(oc4ccccc43)c3c2B1c1cccc2c1N3c1ccccc1S2 ; CC1(C)c2ccccc2-c2c1c1cccc3c1n2B1c2cccc4c2N(c2ccccc2S4)c2cc4c(oc5ccccc54)c-3c21] 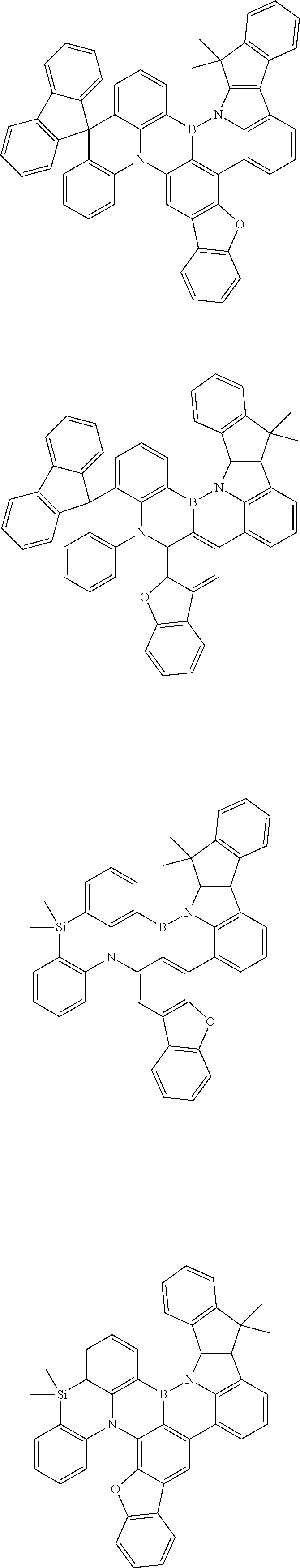 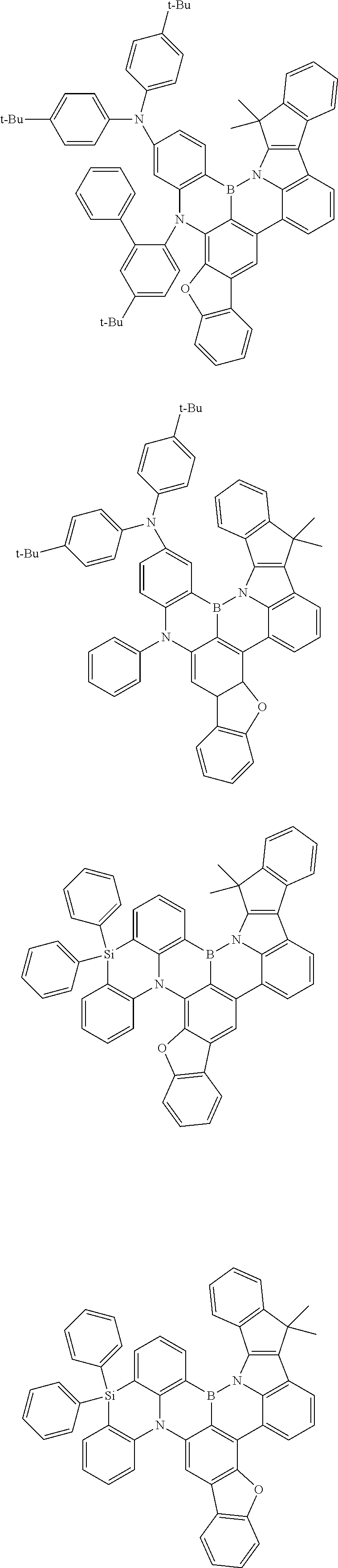 [SMILES: CC(C)(C)c1ccc(N(c2ccc(C(C)(C)C)cc2)c2ccc3c(c2)N(c2ccc(C(C)(C)C)cc2-c2ccccc2)c2c4c(cc5c2oc2ccccc25)-c2cccc5c6c(n(c25)B34)C(C)(C)c2ccccc2-6)cc1 ; CC(C)(C)c1ccc(N(c2ccc(C(C)(C)C)cc2)c2ccc3c(c2)B2C4=C(c5cccc6c7c(n2c56)-c2ccccc2C7(C)C)C2Oc5ccccc5C2C=C4N3c2ccccc2)cc1 ; CC1(C)c2ccccc2-c2c1n1c3c(cccc23)-c2cc3c(oc4ccccc43)c3c2B1c1cccc2c1N3c1ccccc1[Si]2(c1ccccc1)c1ccccc1 ; CC1(C)c2ccccc2-c2c1c1cccc3c1n2B1c2cccc4c2N(c2ccccc2[Si]4(c2ccccc2)c2ccccc2)c2cc4c(oc5ccccc54)c-3c21] 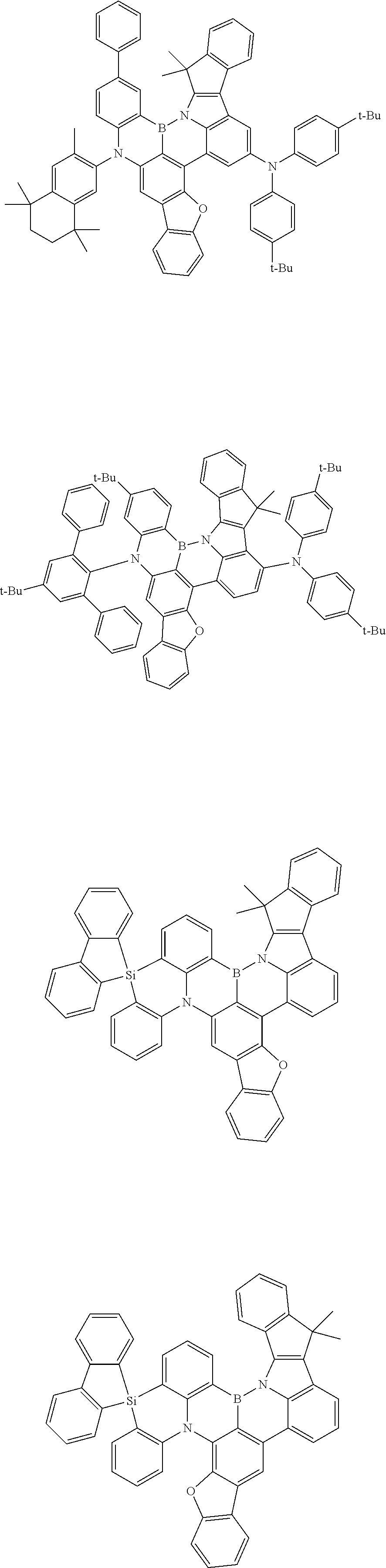 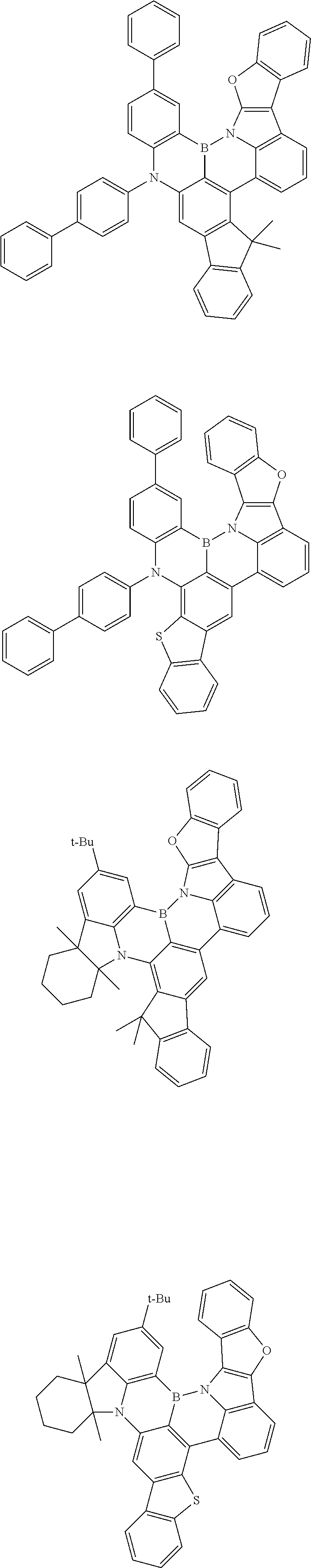 [SMILES: CC1(C)c2ccccc2-c2cc3c4c(c21)-c1cccc2c5c6ccccc6oc5n(c12)B4c1cc(-c2ccccc2)ccc1N3c1ccc(-c2ccccc2)cc1 ; c1ccc(-c2ccc(N3c4ccc(-c5ccccc5)cc4B4c5c(cc6c(sc7ccccc76)c53)-c3cccc5c6oc7ccccc7c6n4c35)cc2)cc1 ; CC(C)(C)c1cc2c3c(c1)C1(C)CCCCC1(C)N3c1c3c(cc4c1C(C)(C)c1ccccc1-4)-c1cccc4c5c6ccccc6oc5n(c14)B23 ; CC(C)(C)c1cc2c3c(c1)C1(C)CCCCC1(C)N3c1cc3c(sc4ccccc43)c3c1B2n1c2c-3cccc2c2oc3ccccc3c21] 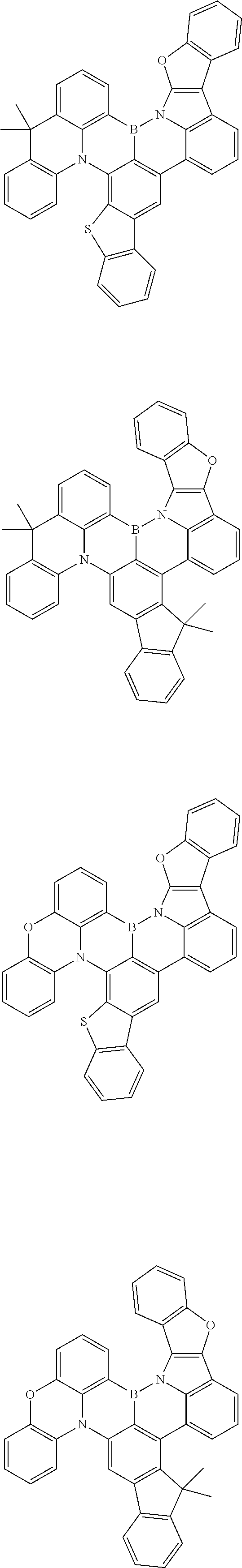 [SMILES: CC1(C)c2ccccc2N2c3c(cccc31)B1c3c(cc4c(sc5ccccc54)c32)-c2cccc3c4c5ccccc5oc4n1c23 ; CC1(C)c2ccccc2N2c3cc4c(c5c3B(c3cccc1c32)n1c2c-5cccc2c2oc3ccccc3c21)C(C)(C)c1ccccc1-4 ; c1ccc2c(c1)Oc1cccc3c1N2c1c2c(cc4c1sc1ccccc14)-c1cccc4c5c6ccccc6oc5n(c14)B32 ; CC1(C)c2ccccc2-c2cc3c4c(c21)-c1cccc2c5oc6ccccc6c5n(c12)B4c1cccc2c1N3c1ccccc1O2] 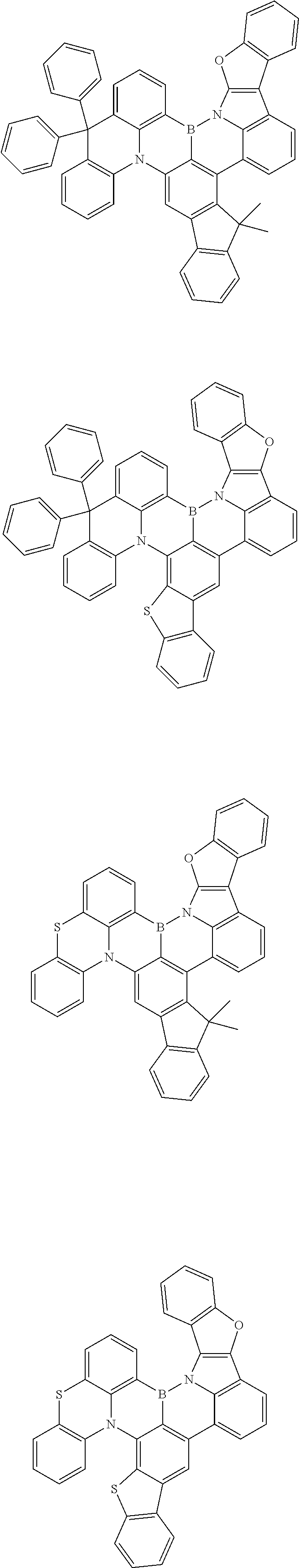 [SMILES: CC1(C)c2ccccc2-c2cc3c4c(c21)-c1cccc2c5c6ccccc6oc5n(c12)B4c1cccc2c1N3c1ccccc1C2(c1ccccc1)c1ccccc1 ; c1ccc(C2(c3ccccc3)c3ccccc3N3c4c(cccc42)B2c4c(cc5c(sc6ccccc65)c43)-c3cccc4c5oc6ccccc6c5n2c34)cc1 ; CC1(C)c2ccccc2-c2cc3c4c(c21)-c1cccc2c5c6ccccc6oc5n(c12)B4c1cccc2c1N3c1ccccc1S2 ; c1ccc2c(c1)Sc1cccc3c1N2c1c2c(cc4c1sc1ccccc14)-c1cccc4c5oc6ccccc6c5n(c14)B32] 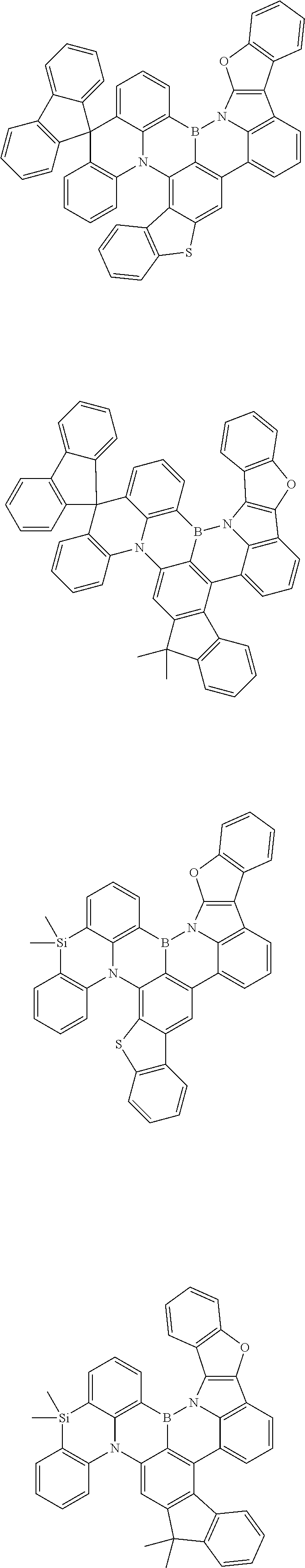 [SMILES: c1ccc2c(c1)-c1ccccc1C21c2ccccc2N2c3c(cccc31)B1c3c(cc4sc5ccccc5c4c32)-c2cccc3c4c5ccccc5oc4n1c23 ; CC1(C)c2ccccc2-c2c1cc1c3c2-c2cccc4c5oc6ccccc6c5n(c24)B3c2cccc3c2N1c1ccccc1C31c2ccccc2-c2ccccc21 ; C[Si]1(C)c2ccccc2N2c3c(cccc31)B1c3c(cc4c(sc5ccccc54)c32)-c2cccc3c4c5ccccc5oc4n1c23 ; CC1(C)c2ccccc2-c2c1cc1c3c2-c2cccc4c5oc6ccccc6c5n(c24)B3c2cccc3c2N1c1ccccc1[Si]3(C)C] 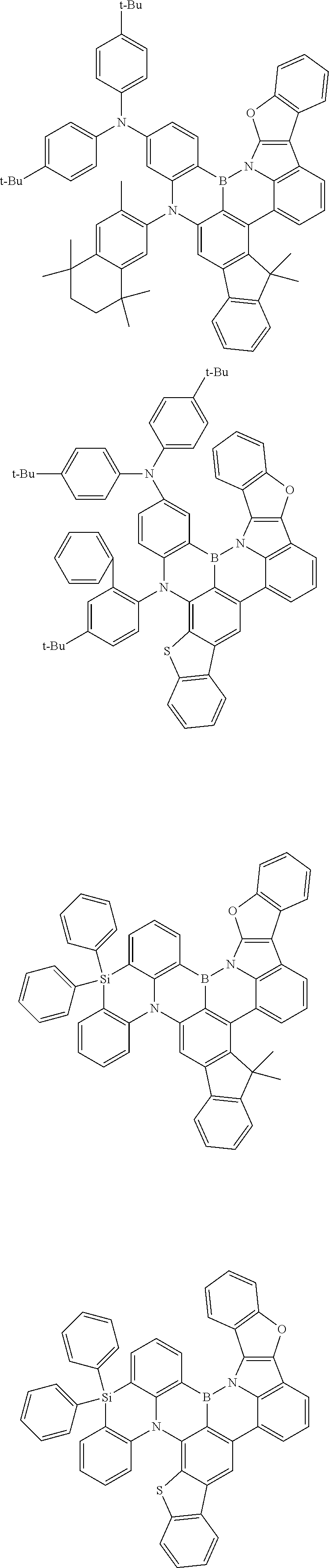 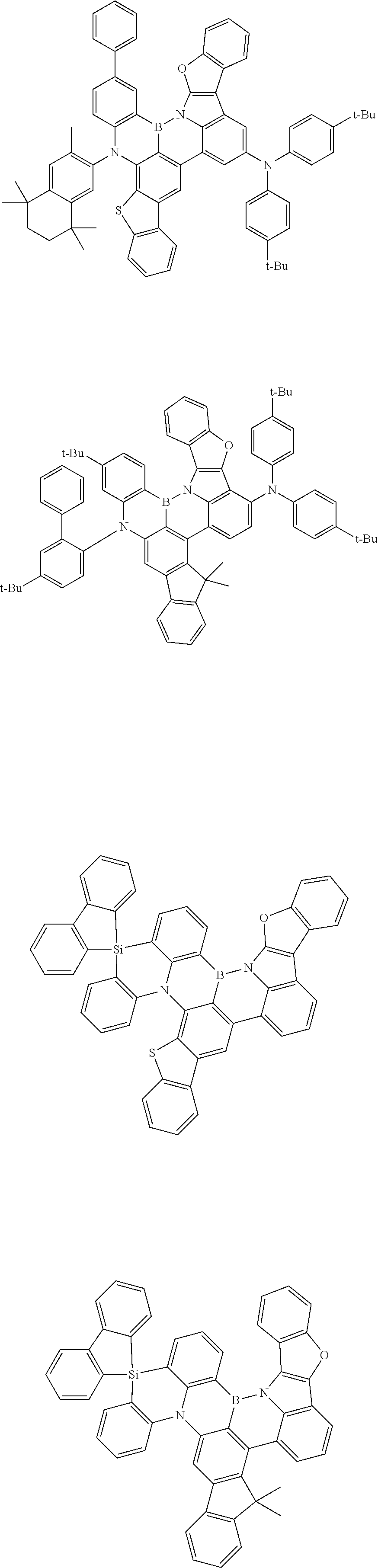 [SMILES: Cc1cc2c(cc1N1c3ccc(-c4ccccc4)cc3B3c4c(cc5c(sc6ccccc65)c41)-c1cc(N(c4ccc(C(C)(C)C)cc4)c4ccc(C(C)(C)C)cc4)cc4c5c6ccccc6oc5n3c14)C(C)(C)CCC2(C)C ; CC(C)(C)c1ccc(N(c2ccc(C(C)(C)C)cc2)c2ccc3c4c2c2oc5ccccc5c2n4B2c4ccc(C(C)(C)C)cc4N(c4ccc(C(C)(C)C)cc4-c4ccccc4)c4cc5c(c-3c42)C(C)(C)c2ccccc2-5)cc1 ; c1ccc2c(c1)-c1ccccc1[Si]21c2ccccc2N2c3c(cccc31)B1c3c(cc4c(sc5ccccc54)c32)-c2cccc3c4c5ccccc5oc4n1c23 ; CC1(C)c2ccccc2-c2cc3c4c(c21)-c1cccc2c5oc6ccccc6c5n(c12)B4c1cccc2c1N3c1ccccc1[Si]21c2ccccc2-c2ccccc21] 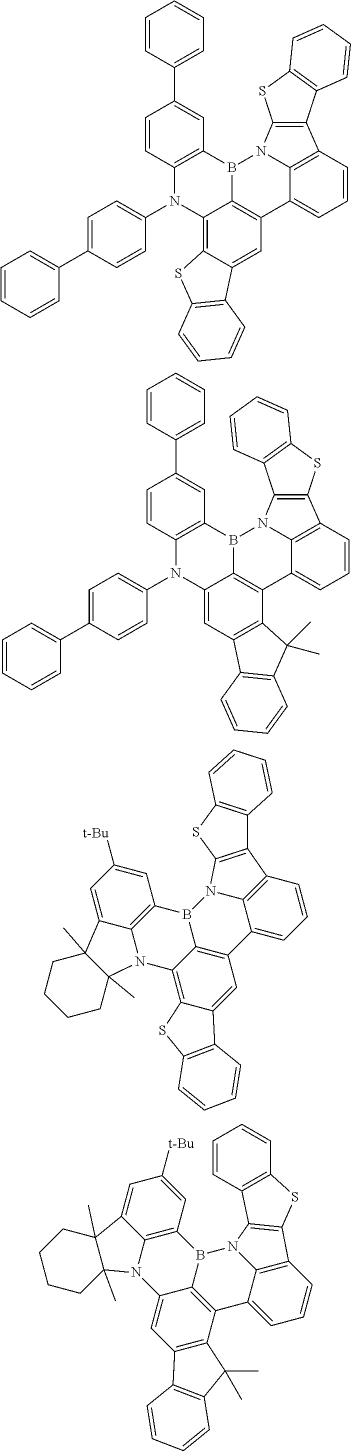 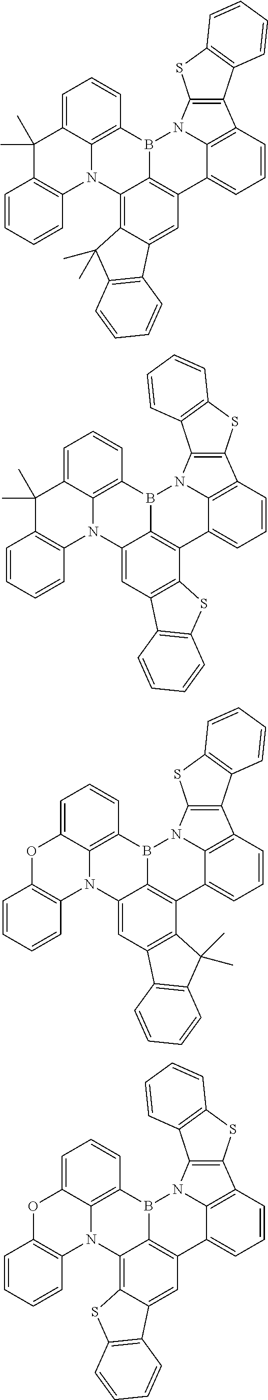 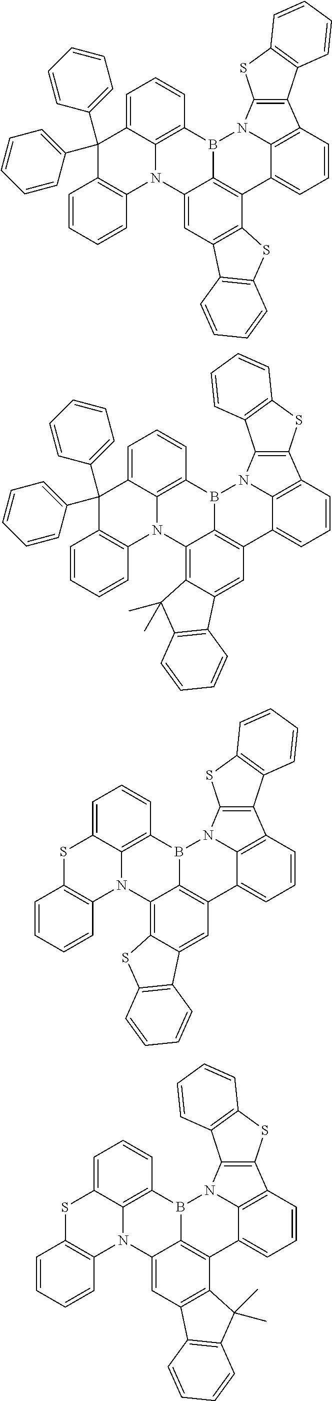 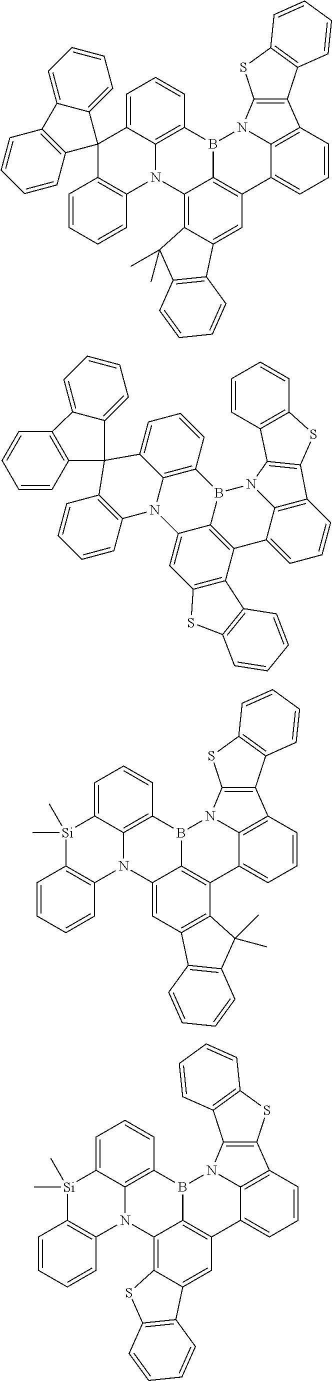 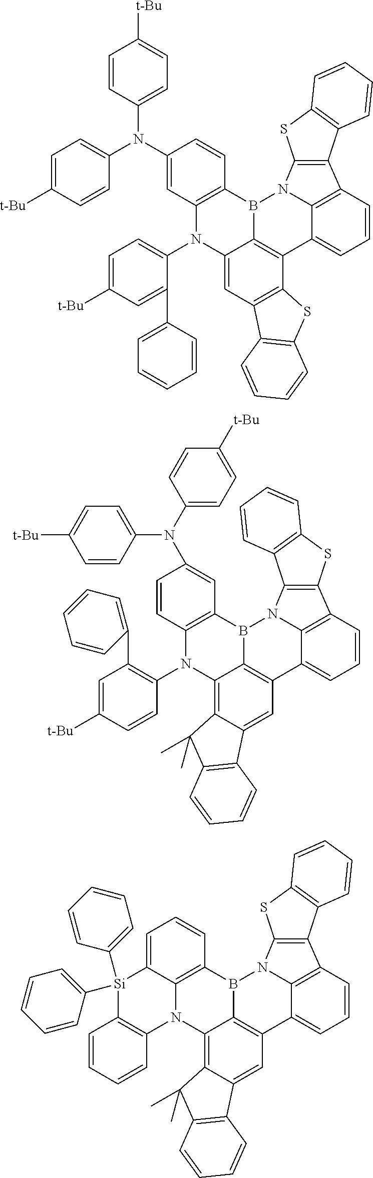 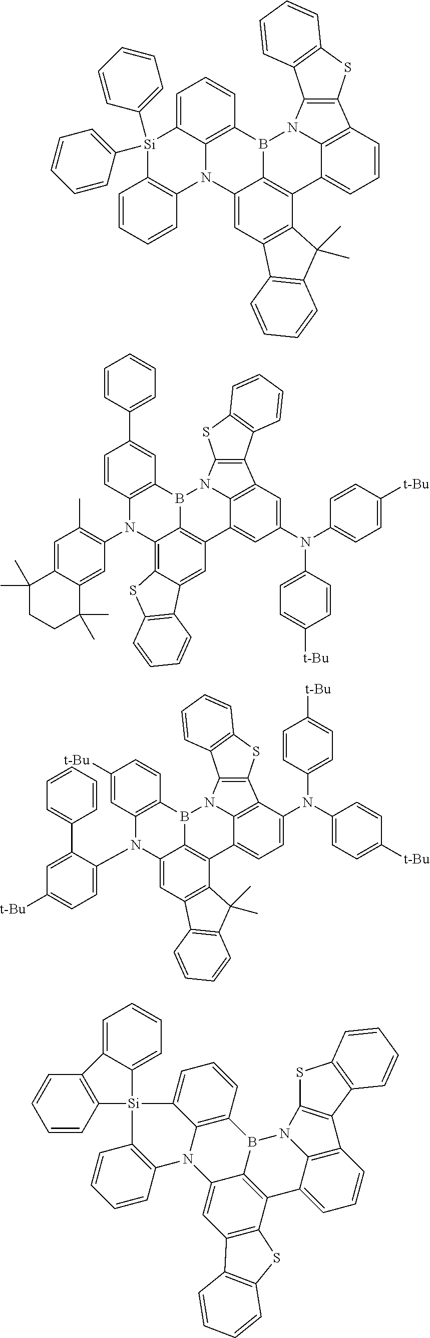 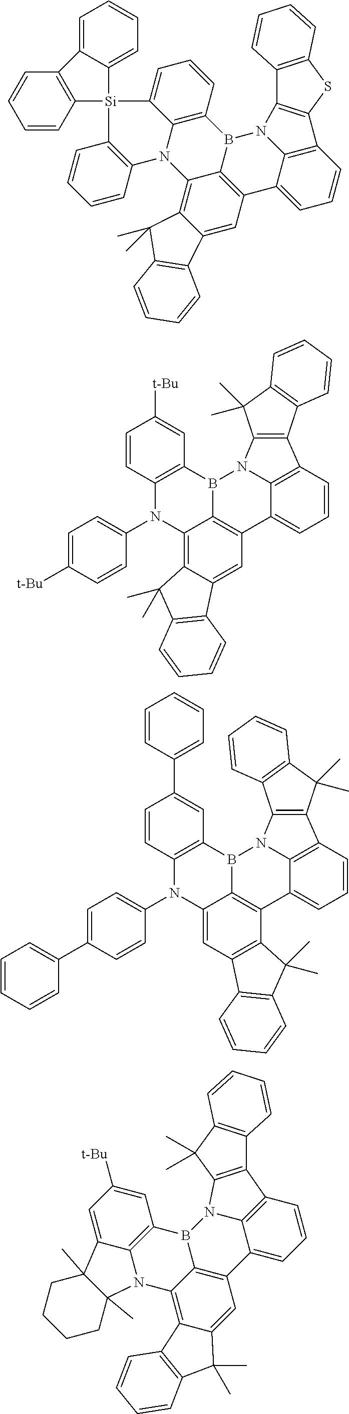 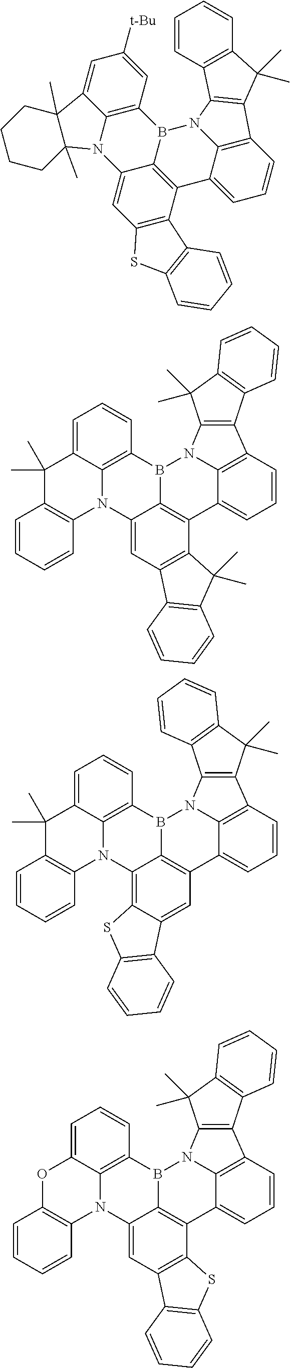 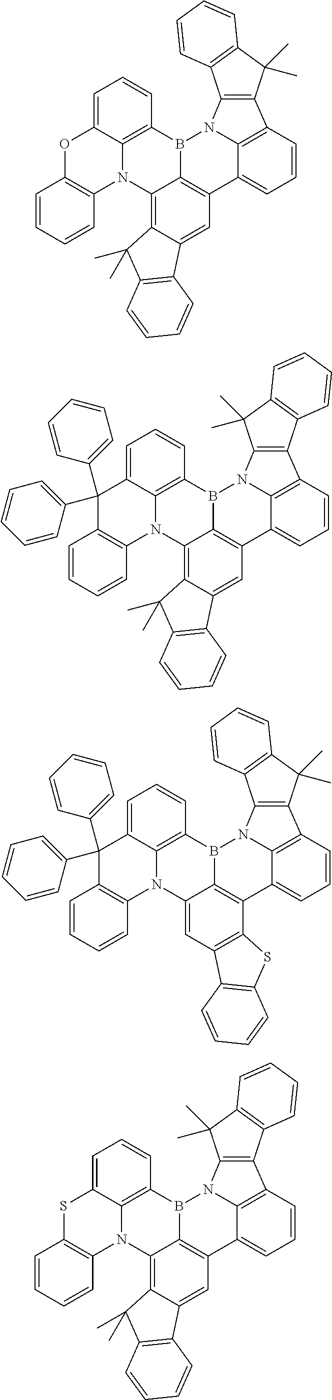 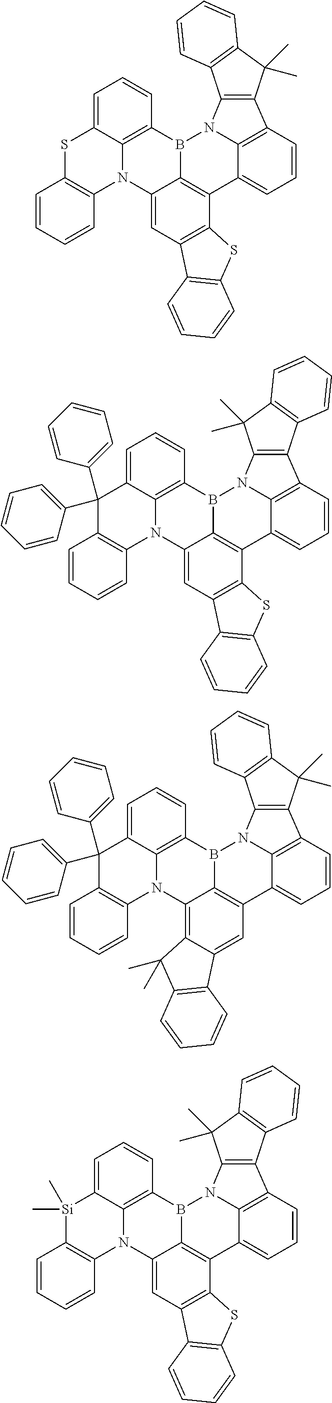 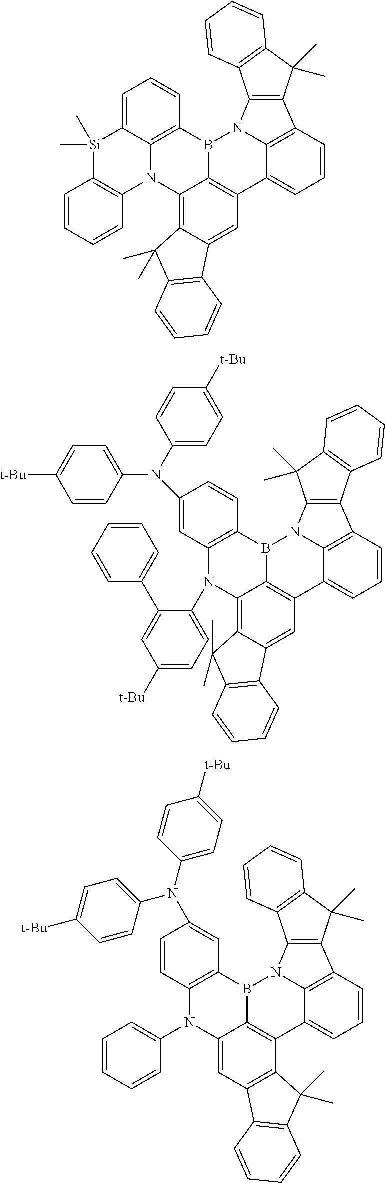 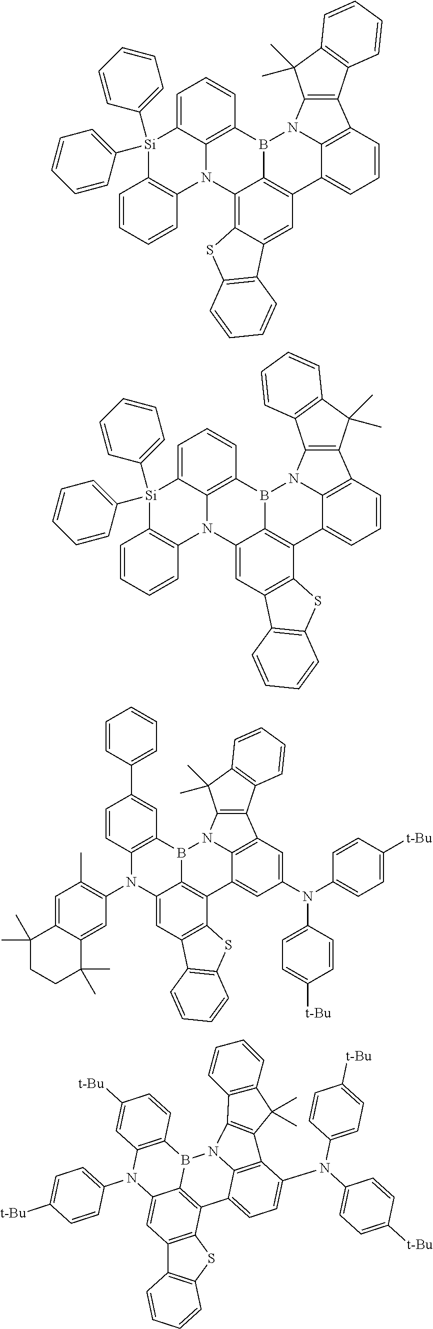 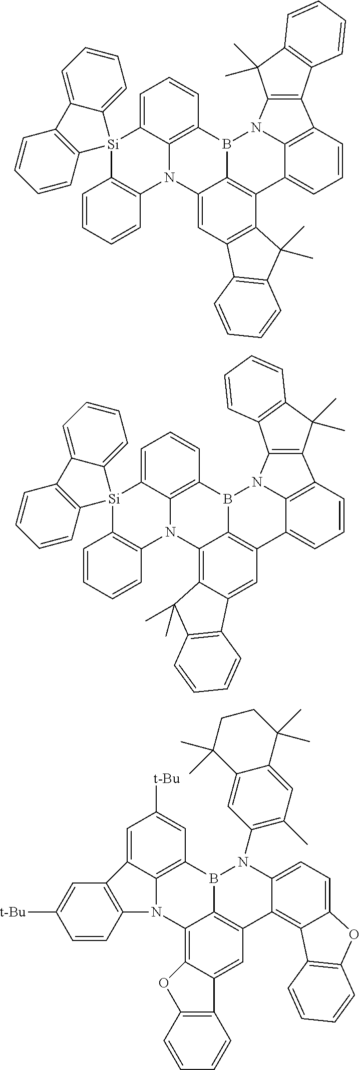 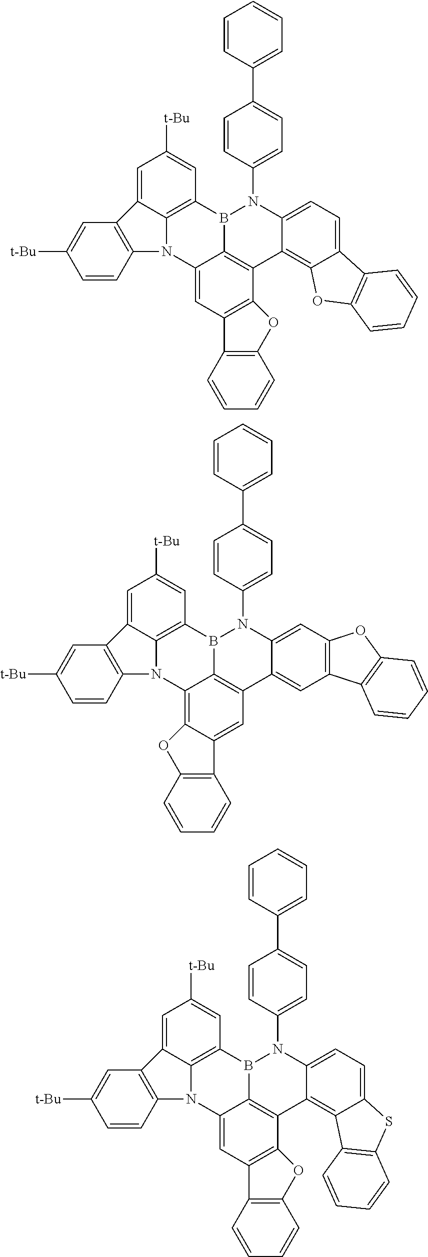 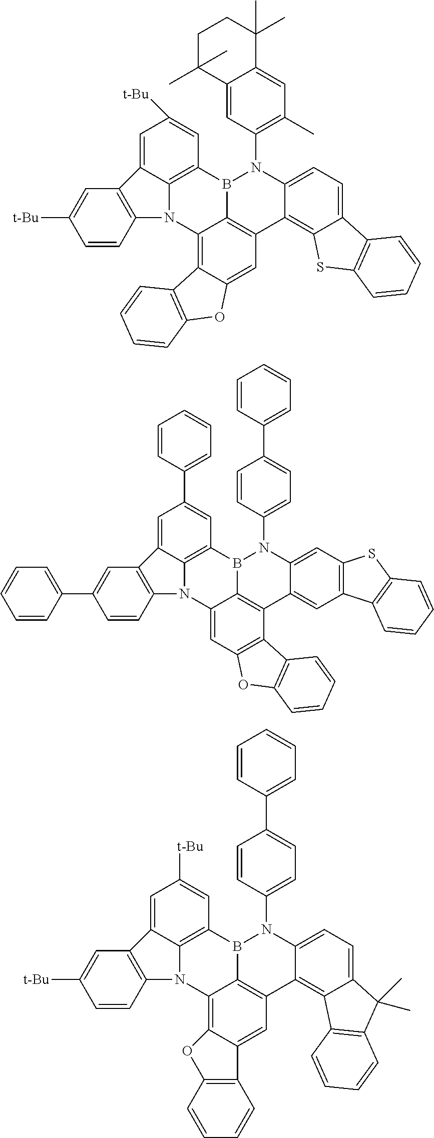 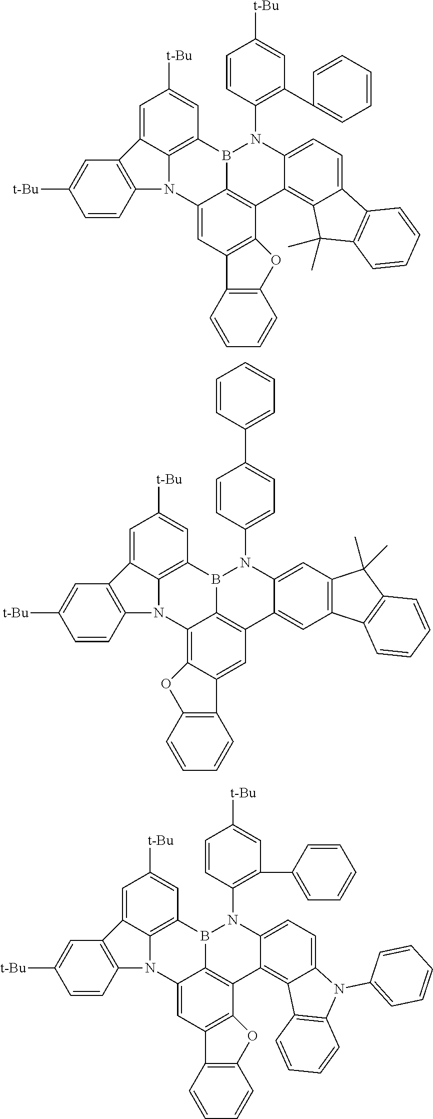 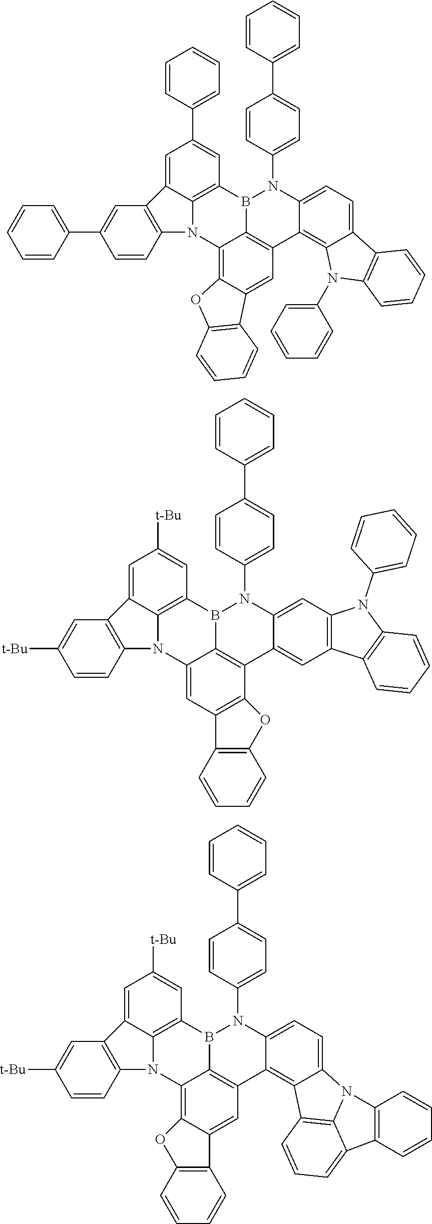 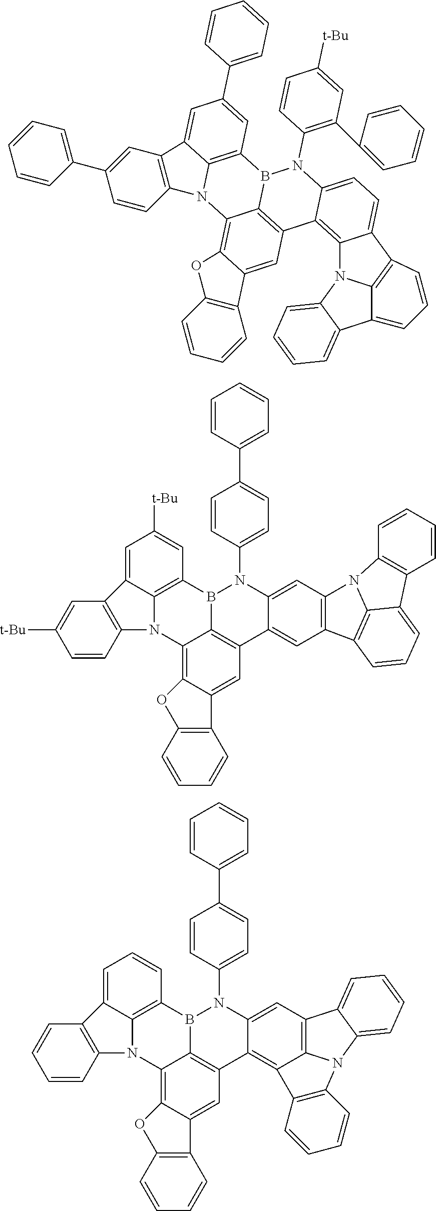 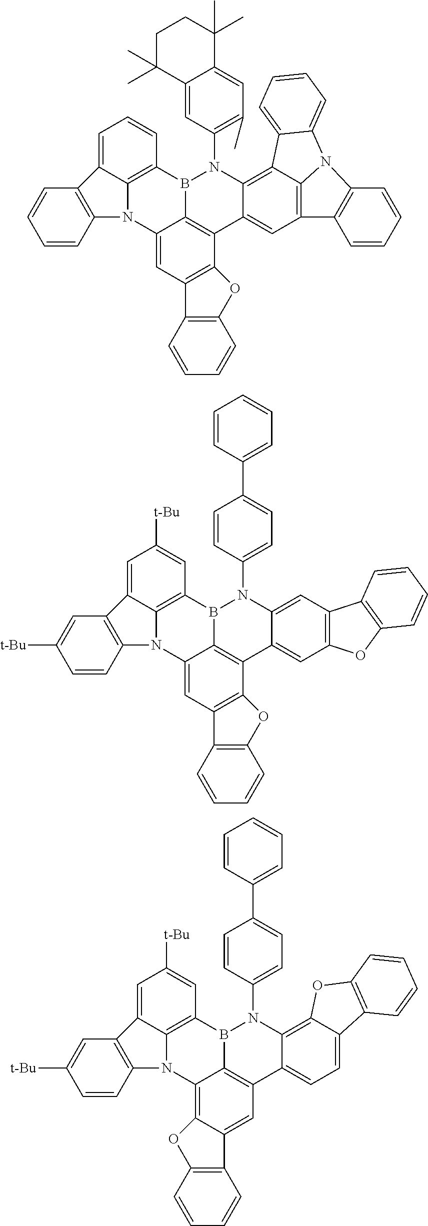 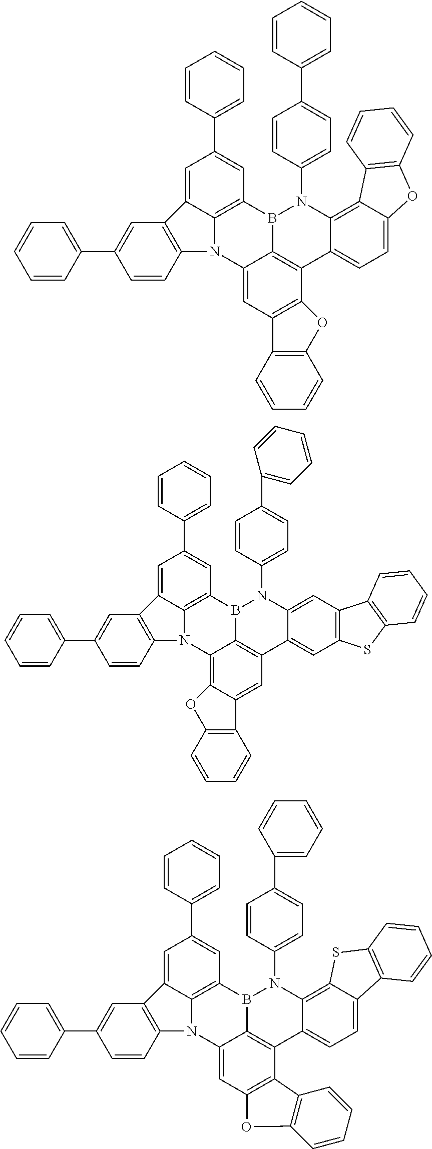 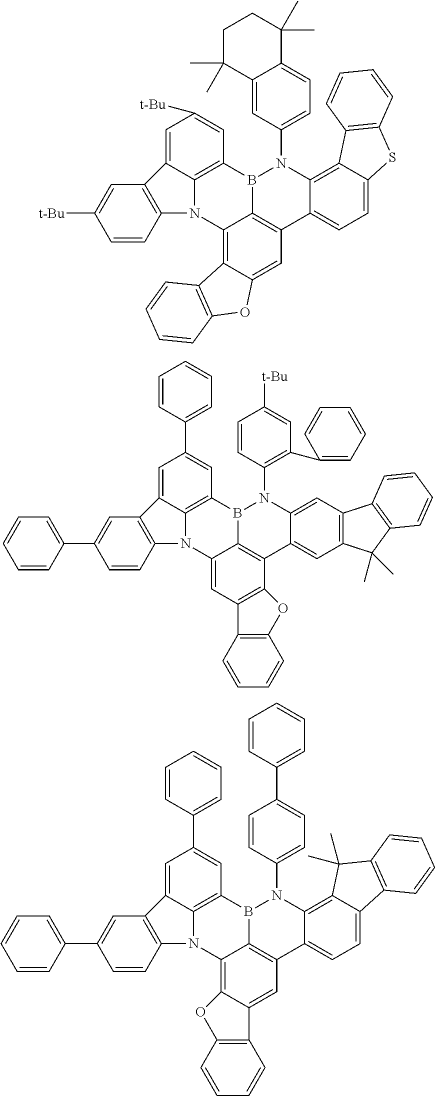 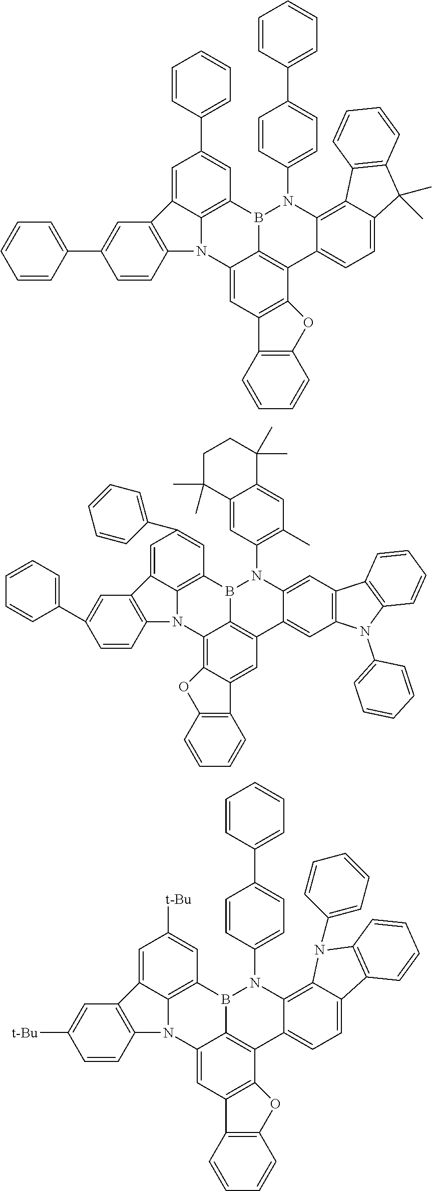 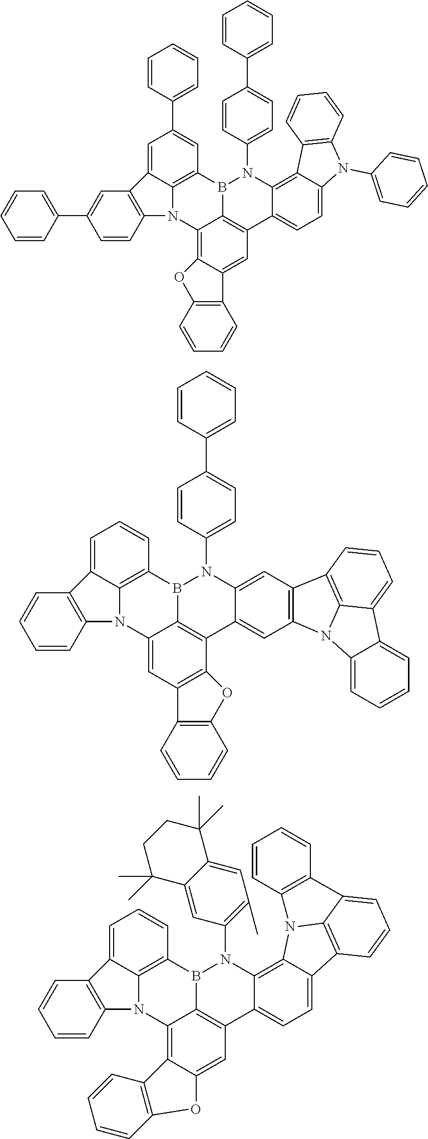 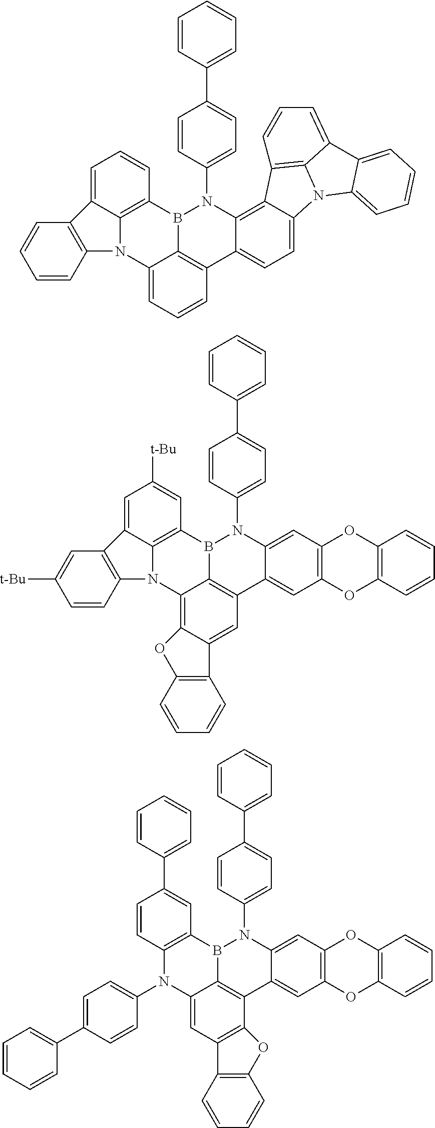 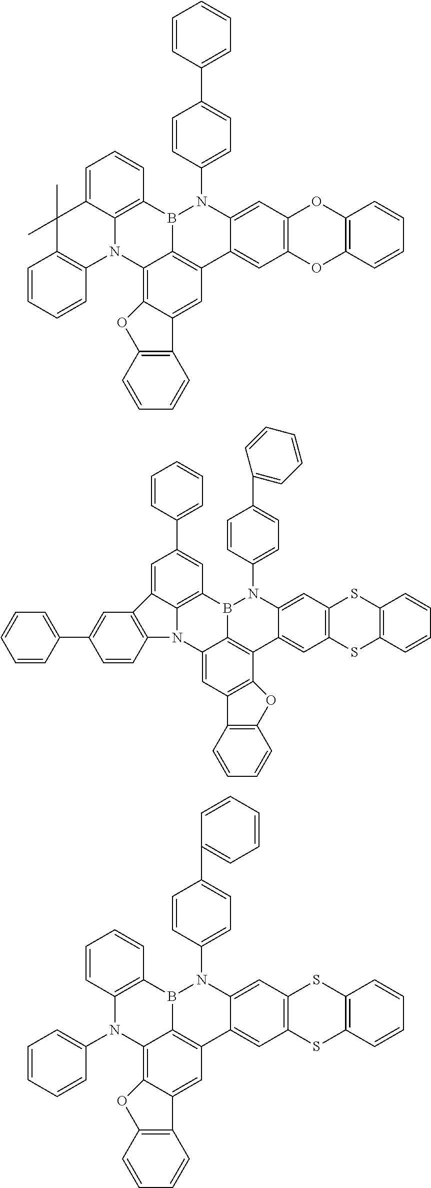 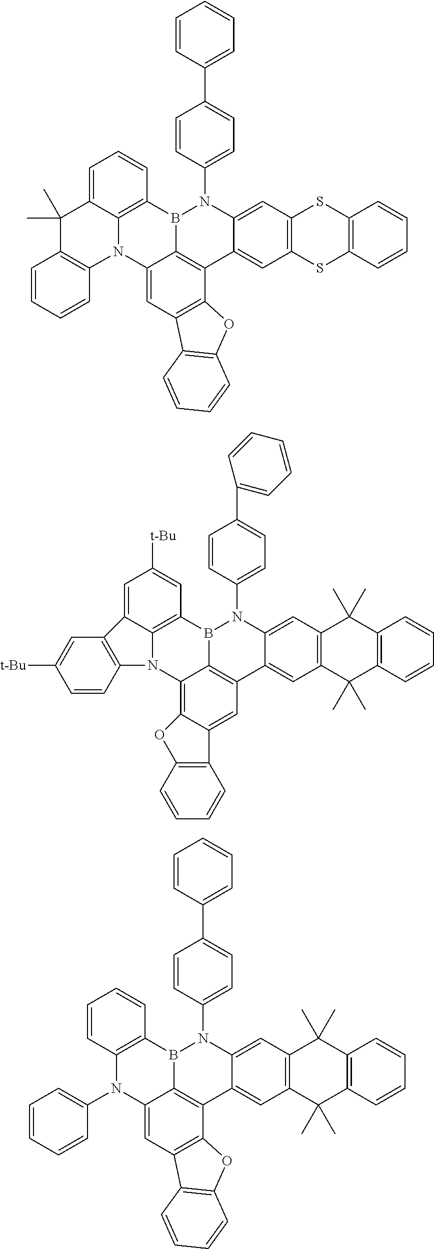 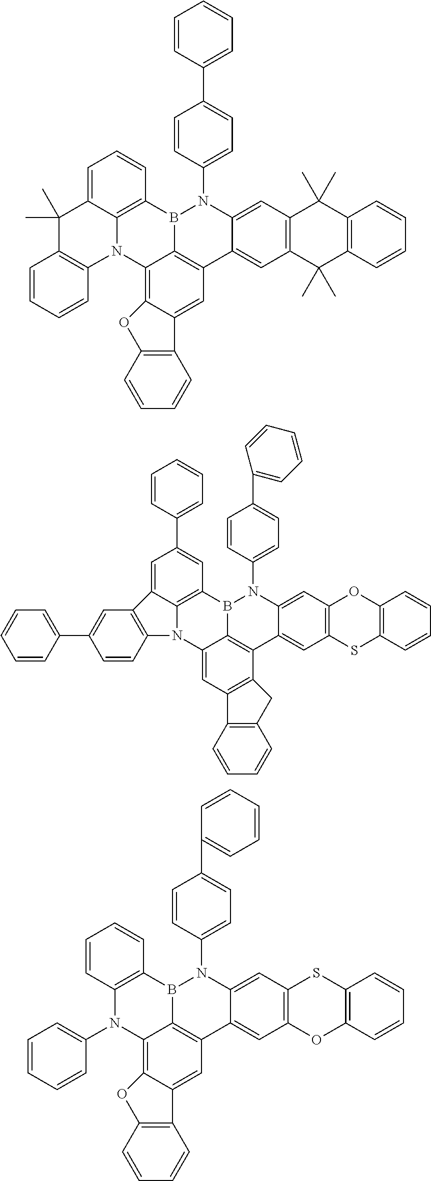 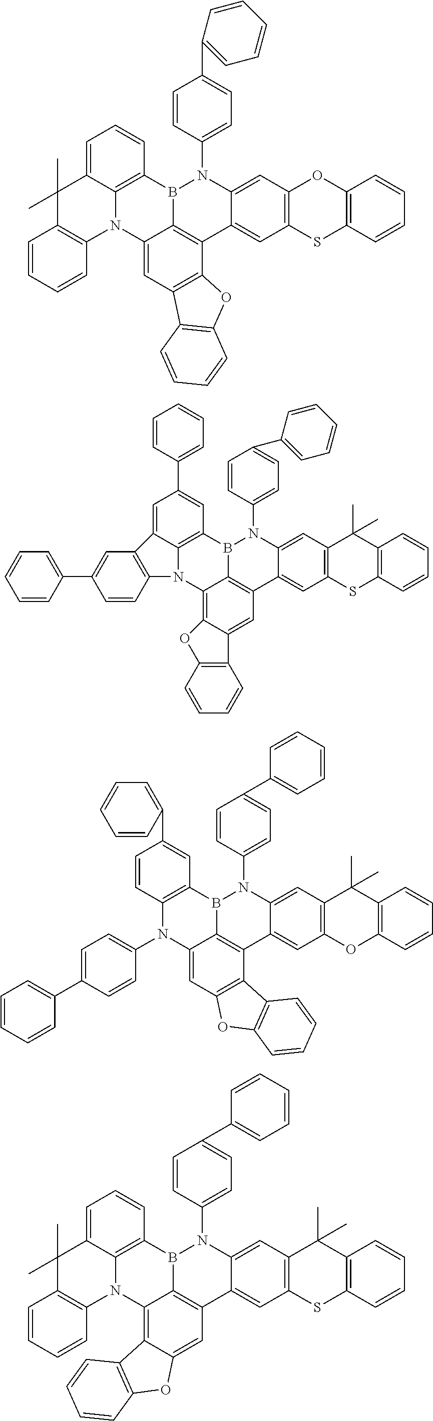 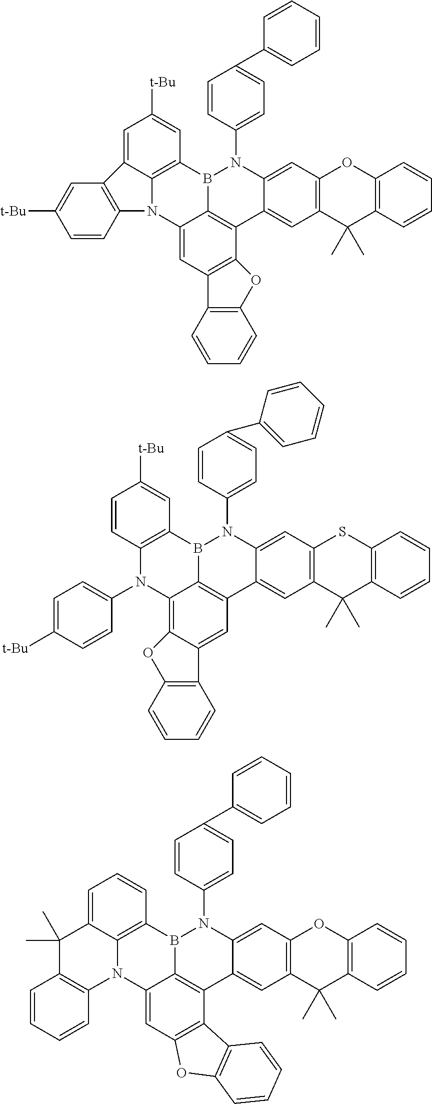 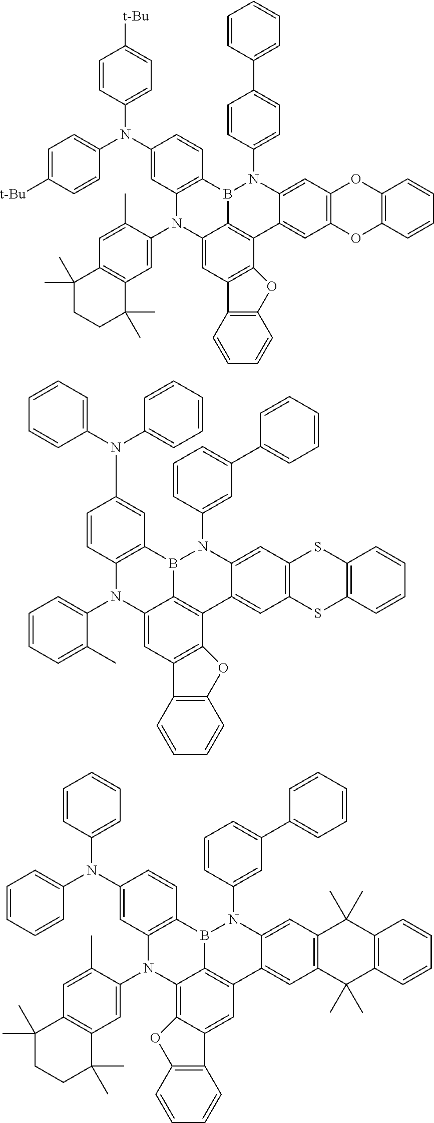 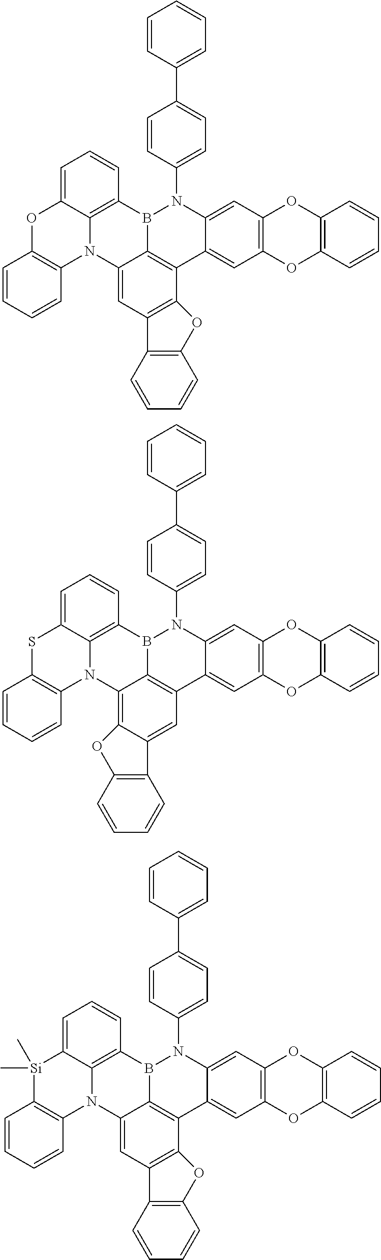 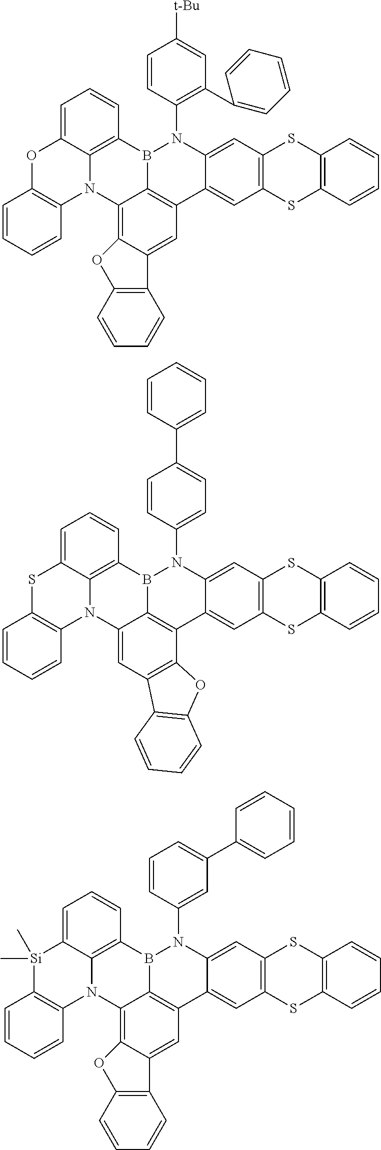 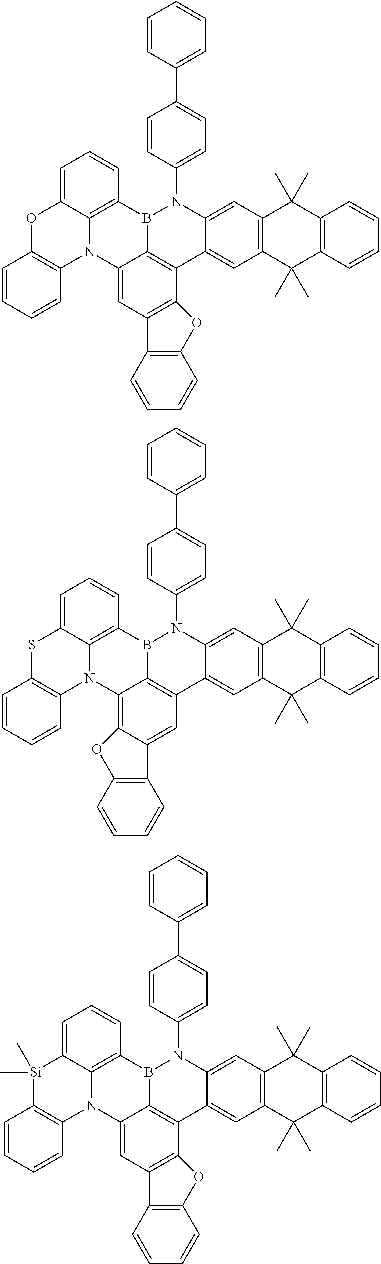 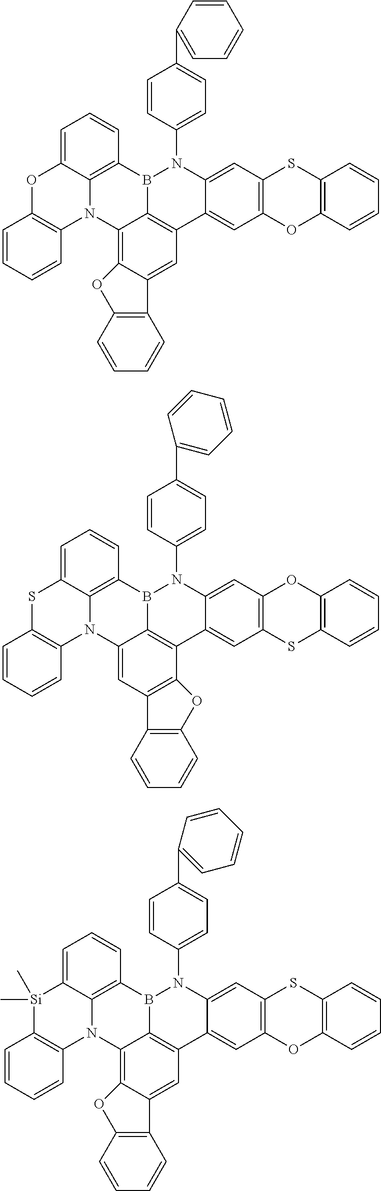 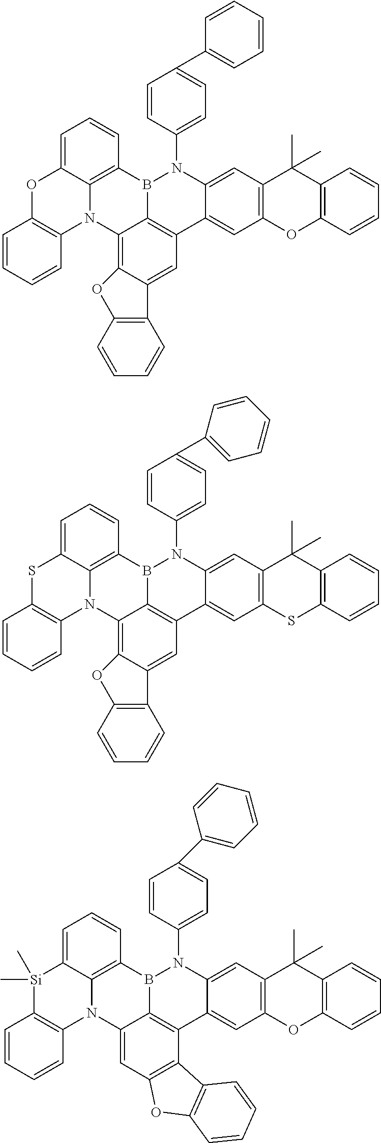 [SMILES: CC1(C)c2ccccc2Oc2cc3c(cc21)N(c1ccc(-c2ccccc2)cc1)B1c2cccc4c2N(c2ccccc2O4)c2c1c-3cc1c2oc2ccccc21 ; CC1(C)c2ccccc2Sc2cc3c(cc21)N(c1ccc(-c2ccccc2)cc1)B1c2cccc4c2N(c2ccccc2S4)c2c1c-3cc1c2oc2ccccc21 ; CC1(C)c2ccccc2Oc2cc3c(cc21)N(c1ccc(-c2ccccc2)cc1)B1c2cccc4c2N(c2ccccc2[Si]4(C)C)c2cc4oc5ccccc5c4c-3c21] 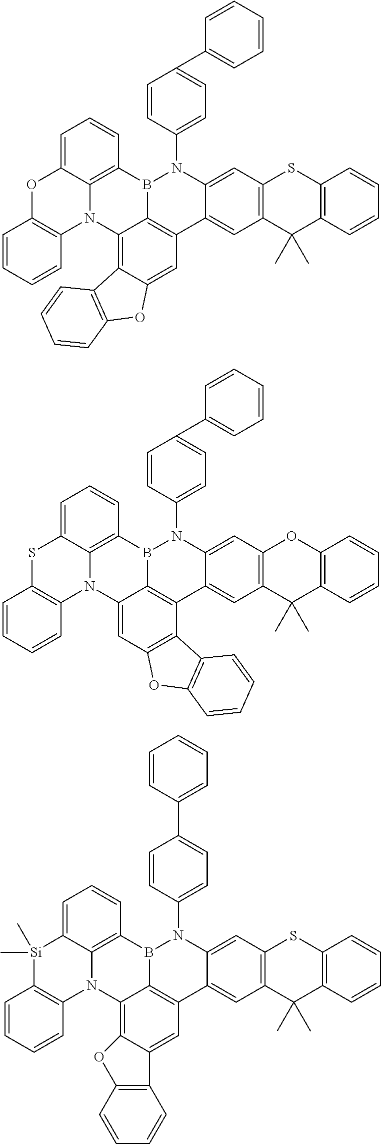 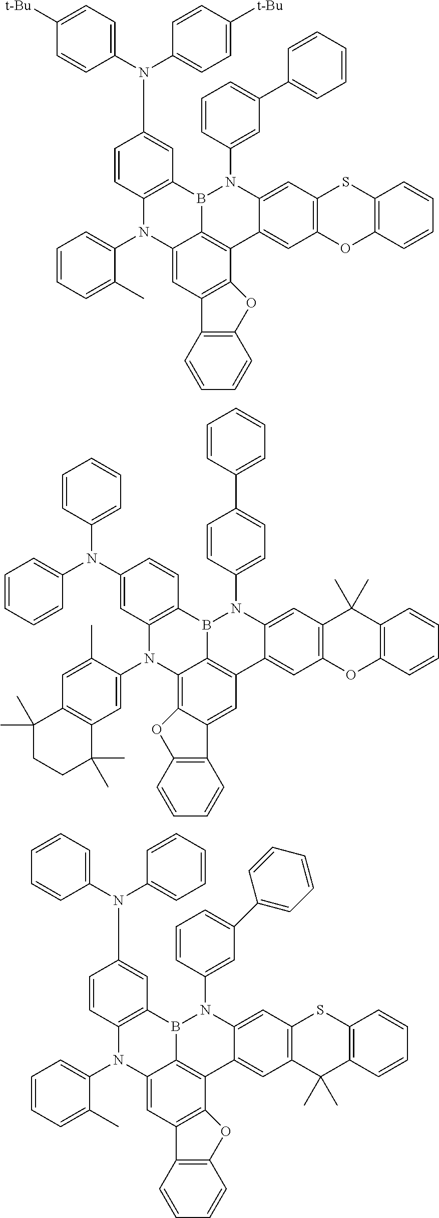 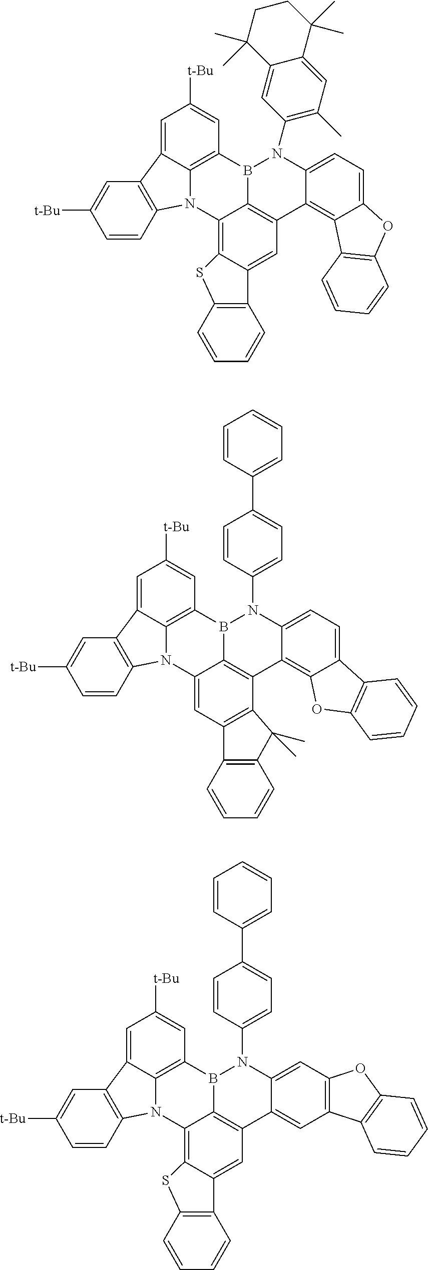 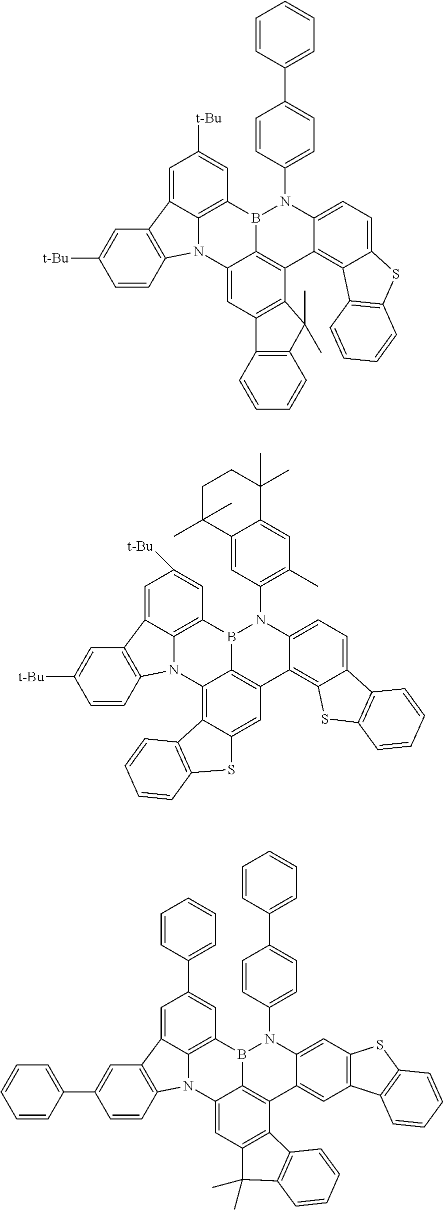 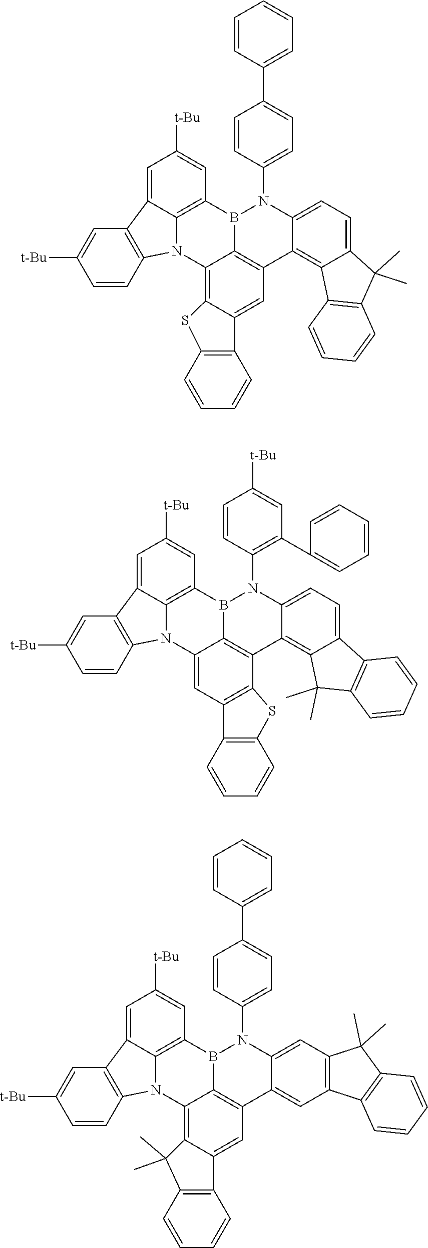 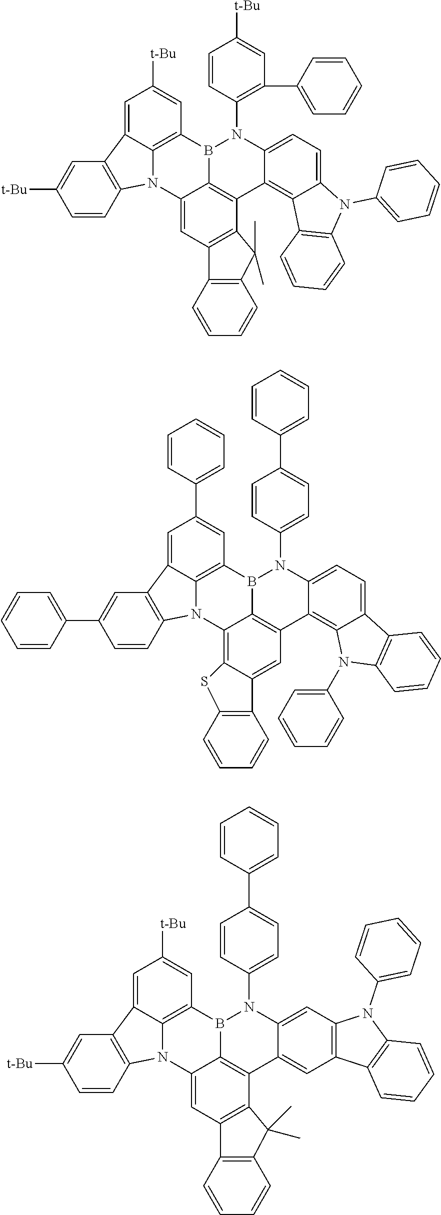 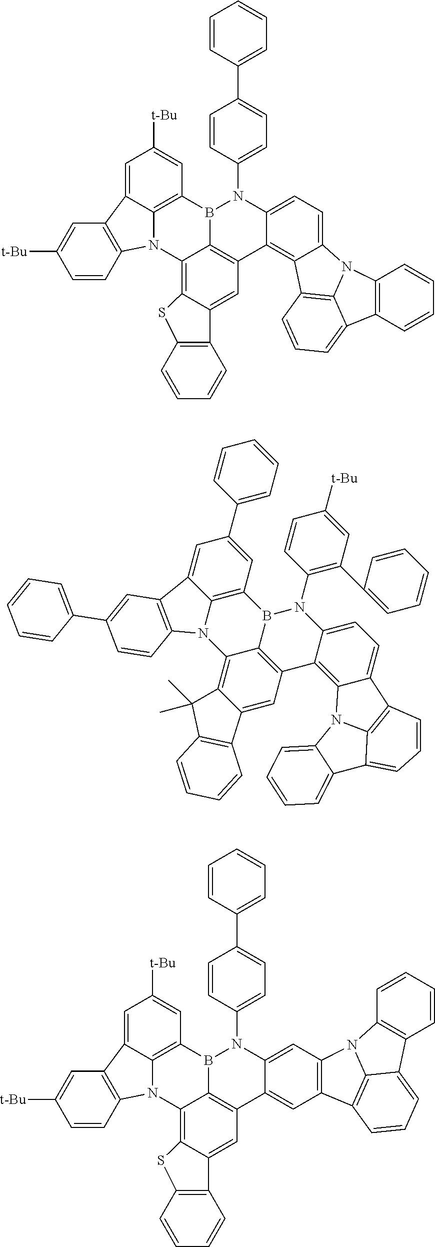 [SMILES: CC(C)(C)c1ccc2c(c1)c1cc(C(C)(C)C)cc3c1n2-c1c2c(cc4c1sc1ccccc14)-c1c(ccc4c1c1cccc5c6ccccc6n4c51)N(c1ccc(-c4ccccc4)cc1)B23 ; CC(C)(C)c1ccc(N2B3c4c(cc5c(c4-n4c6ccc(-c7ccccc7)cc6c6cc(-c7ccccc7)cc3c64)C(C)(C)c3ccccc3-5)-c3c2ccc2c4cccc5c6ccccc6n(c32)c54)c(-c2ccccc2)c1 ; CC(C)(C)c1ccc2c(c1)c1cc(C(C)(C)C)cc3c1n2-c1c2c(cc4c1sc1ccccc14)-c1cc4c5cccc6c7ccccc7n(c4cc1N(c1ccc(-c4ccccc4)cc1)B23)c65] 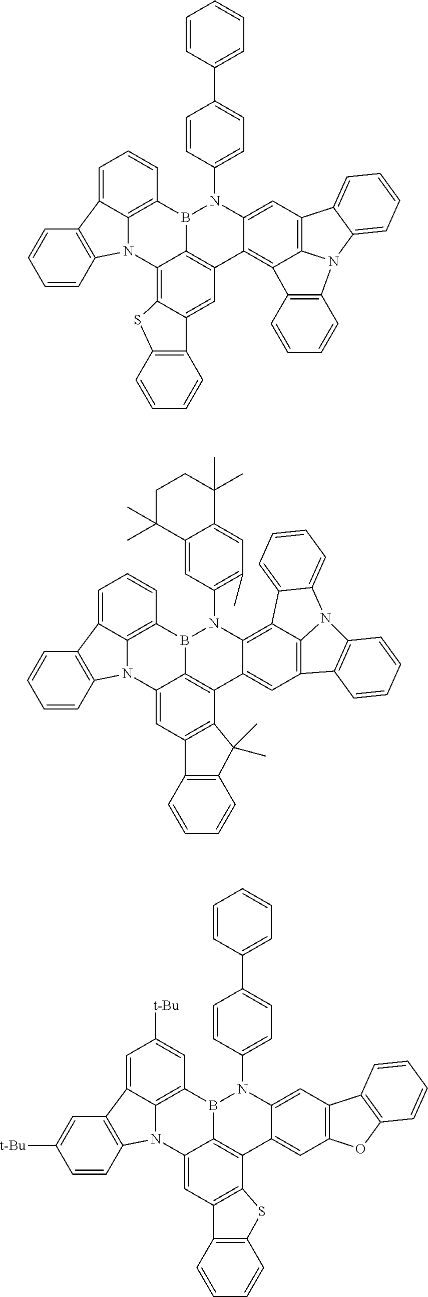 [SMILES: c1ccc(-c2ccc(N3B4c5c(cc6c(sc7ccccc76)c5-n5c6ccccc6c6cccc4c65)-c4c3cc3c5ccccc5n5c6ccccc6c4c35)cc2)cc1 ; Cc1cc2c(cc1N1B3c4c(cc5c(c4-c4cc6c7ccccc7n7c8ccccc8c(c41)c67)C(C)(C)c1ccccc1-5)-n1c4ccccc4c4cccc3c41)C(C)(C)CCC2(C)C ; CC(C)(C)c1ccc2c(c1)c1cc(C(C)(C)C)cc3c1n2-c1cc2c(sc4ccccc42)c2c1B3N(c1ccc(-c3ccccc3)cc1)c1cc3c(cc1-2)oc1ccccc13] 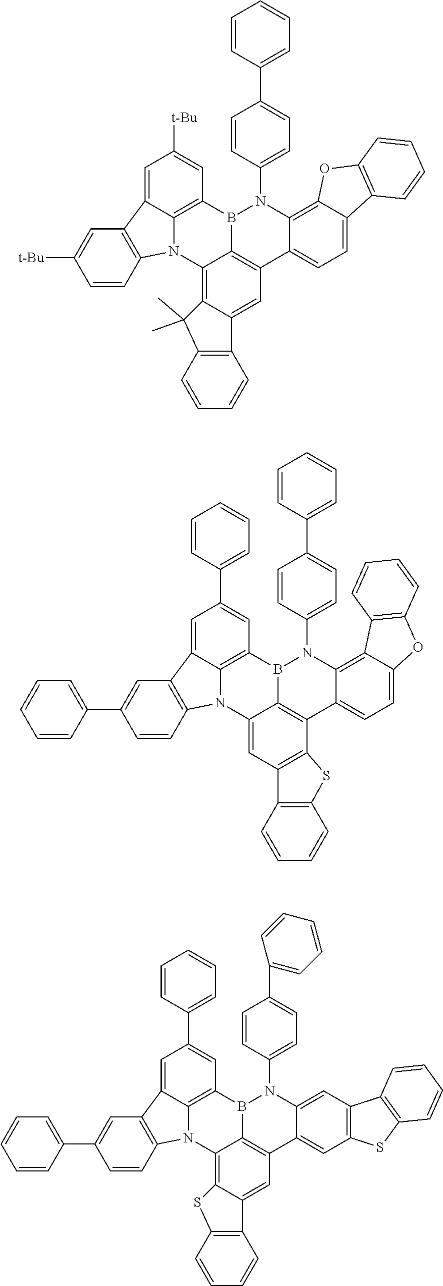 [SMILES: CC(C)(C)c1ccc2c(c1)c1cc(C(C)(C)C)cc3c1n2-c1c2c(cc4c1C(C)(C)c1ccccc1-4)-c1ccc4c(oc5ccccc54)c1N(c1ccc(-c4ccccc4)cc1)B23 ; c1ccc(-c2ccc(N3B4c5c(cc6c(sc7ccccc76)c5-c5ccc6oc7ccccc7c6c53)-n3c5ccc(-c6ccccc6)cc5c5cc(-c6ccccc6)cc4c53)cc2)cc1 ; c1ccc(-c2ccc(N3B4c5c(cc6c(sc7ccccc76)c5-n5c6ccc(-c7ccccc7)cc6c6cc(-c7ccccc7)cc4c65)-c4cc5sc6ccccc6c5cc43)cc2)cc1] 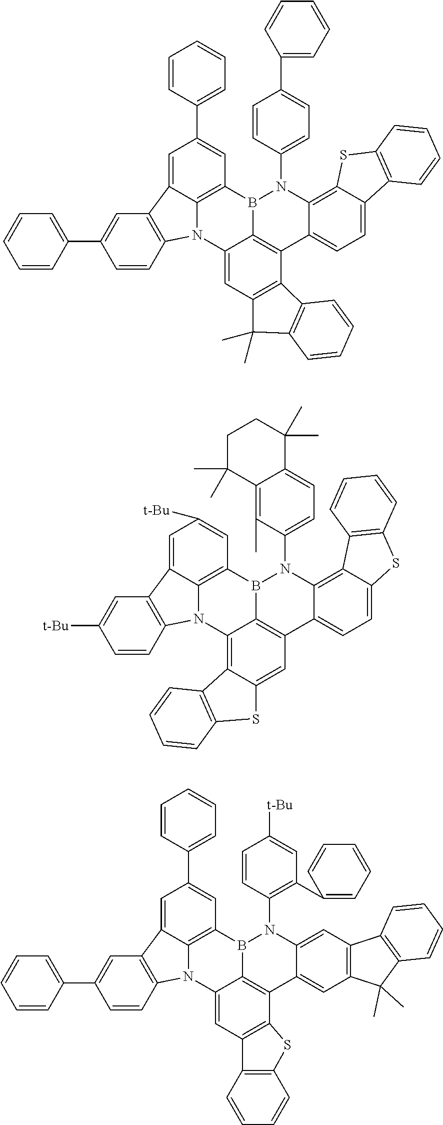 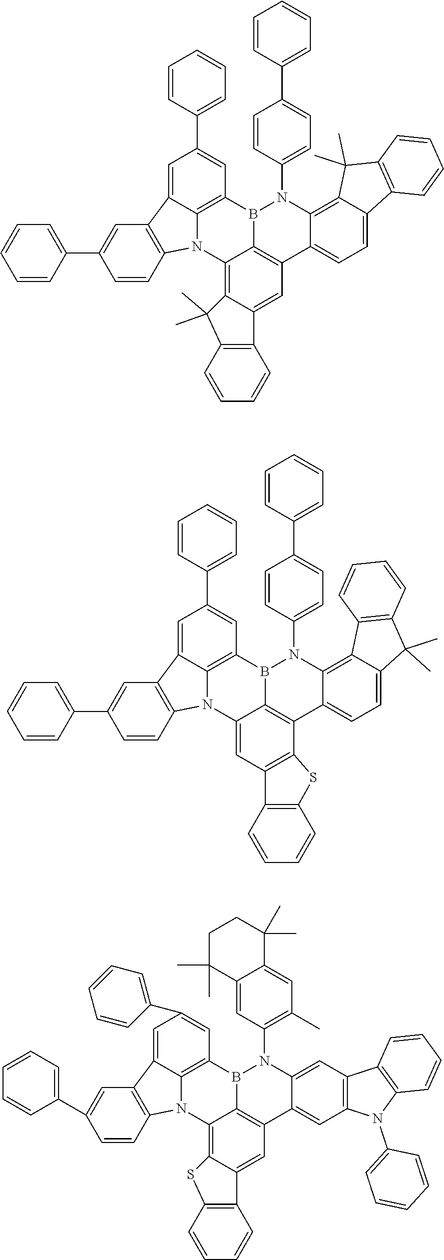 [SMILES: CC1(C)c2ccccc2-c2ccc3c(c21)N(c1ccc(-c2ccccc2)cc1)B1c2c-3cc3c(c2-n2c4ccc(-c5ccccc5)cc4c4cc(-c5ccccc5)cc1c42)C(C)(C)c1ccccc1-3 ; CC1(C)c2ccccc2-c2c1ccc1c2N(c2ccc(-c3ccccc3)cc2)B2c3c(cc4c(sc5ccccc54)c3-1)-n1c3ccc(-c4ccccc4)cc3c3cc(-c4ccccc4)cc2c31 ; Cc1cc2c(cc1N1B3c4c(cc5c(sc6ccccc65)c4-n4c5ccc(-c6ccccc6)cc5c5cc(-c6ccccc6)cc3c54)-c3cc4c(cc31)c1ccccc1n4-c1ccccc1)C(C)(C)CCC2(C)C] 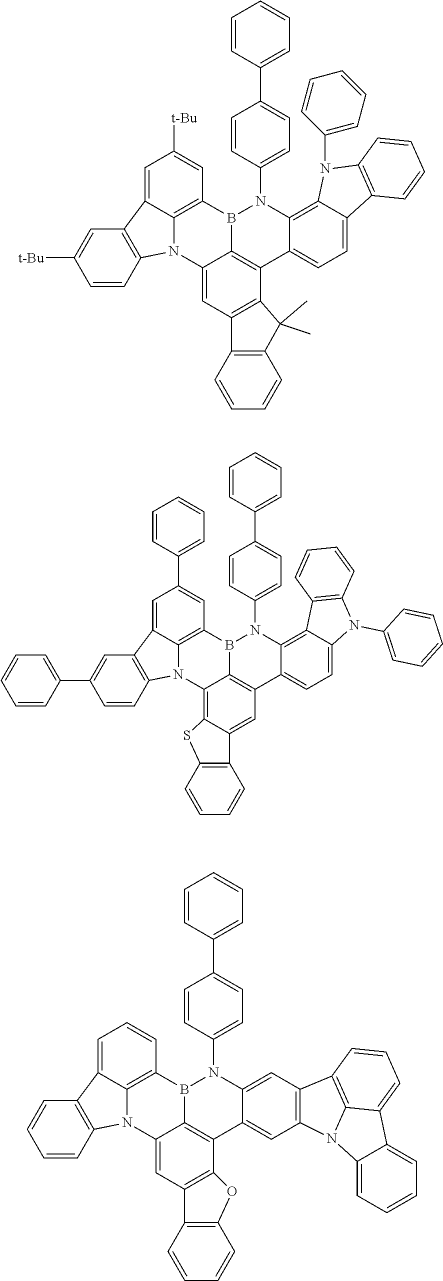 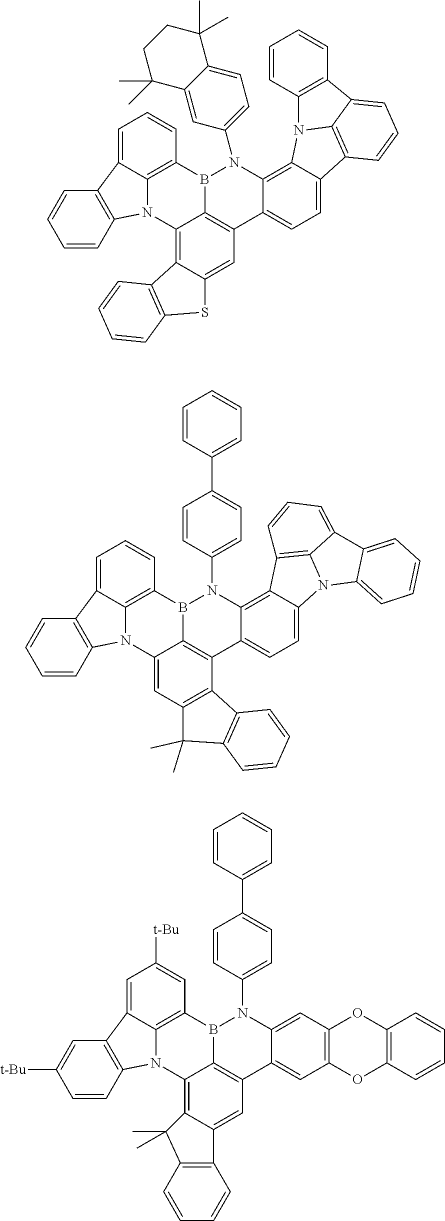 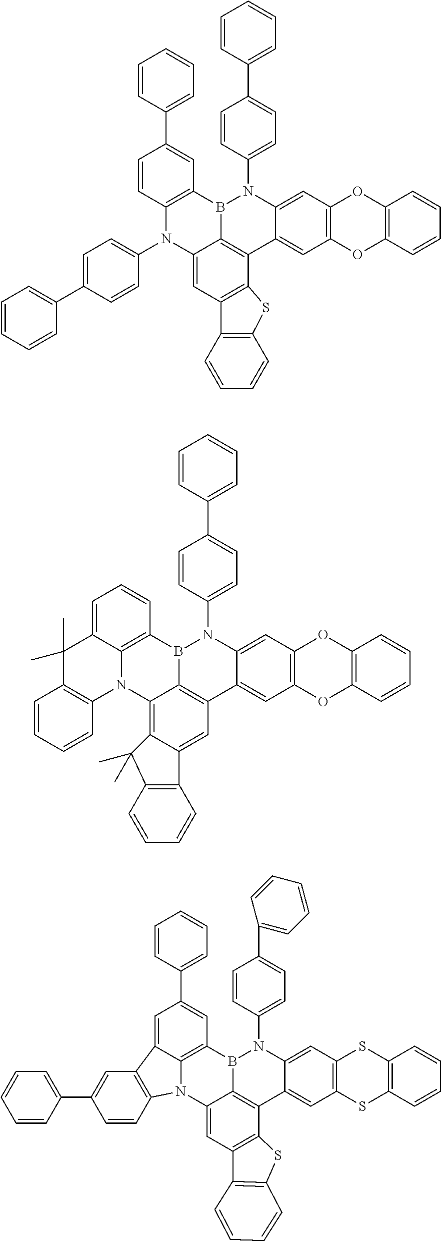 [SMILES: c1ccc(-c2ccc(N3B4c5cc(-c6ccccc6)ccc5N(c5ccc(-c6ccccc6)cc5)c5cc6c(sc7ccccc76)c(c54)-c4cc5c(cc43)Oc3ccccc3O5)cc2)cc1 ; CC1(C)c2ccccc2N2c3c(cccc31)B1c3c(cc4c(c32)C(C)(C)c2ccccc2-4)-c2cc3c(cc2N1c1ccc(-c2ccccc2)cc1)Oc1ccccc1O3 ; c1ccc(-c2ccc(N3B4c5c(cc6c(sc7ccccc76)c5-c5cc6c(cc53)Sc3ccccc3S6)-n3c5ccc(-c6ccccc6)cc5c5cc(-c6ccccc6)cc4c53)cc2)cc1] 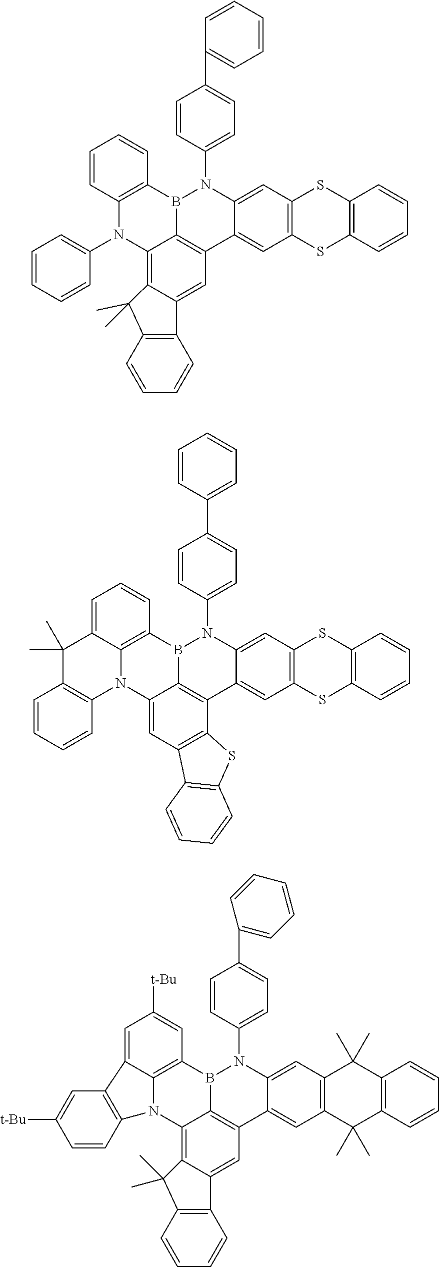 [SMILES: CC1(C)c2ccccc2-c2cc3c4c(c21)N(c1ccccc1)c1ccccc1B4N(c1ccc(-c2ccccc2)cc1)c1cc2c(cc1-3)Sc1ccccc1S2 ; CC1(C)c2ccccc2N2c3cc4c(sc5ccccc54)c4c3B(c3cccc1c32)N(c1ccc(-c2ccccc2)cc1)c1cc2c(cc1-4)Sc1ccccc1S2 ; CC(C)(C)c1ccc2c(c1)c1cc(C(C)(C)C)cc3c1n2-c1c2c(cc4c1C(C)(C)c1ccccc1-4)-c1cc4c(cc1N(c1ccc(-c5ccccc5)cc1)B23)C(C)(C)c1ccccc1C4(C)C] 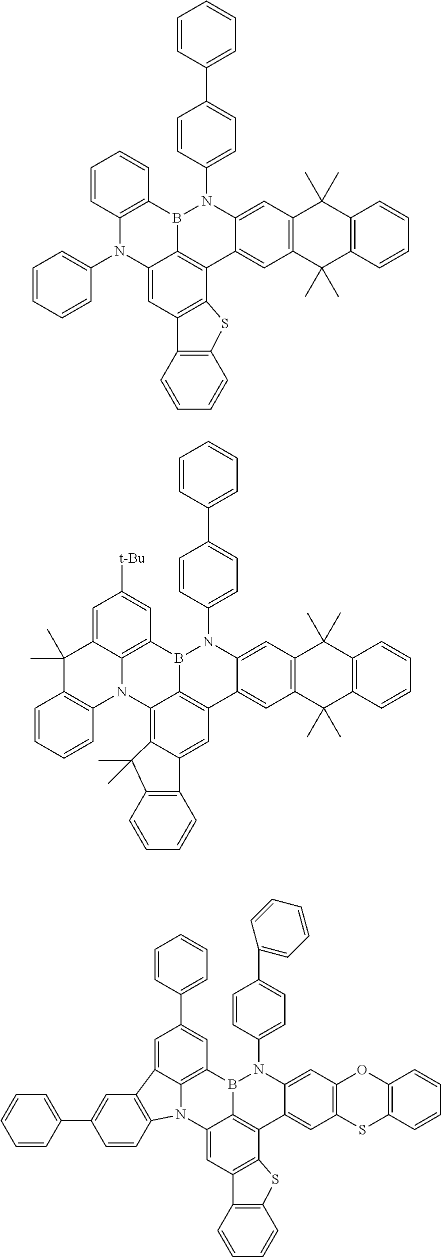 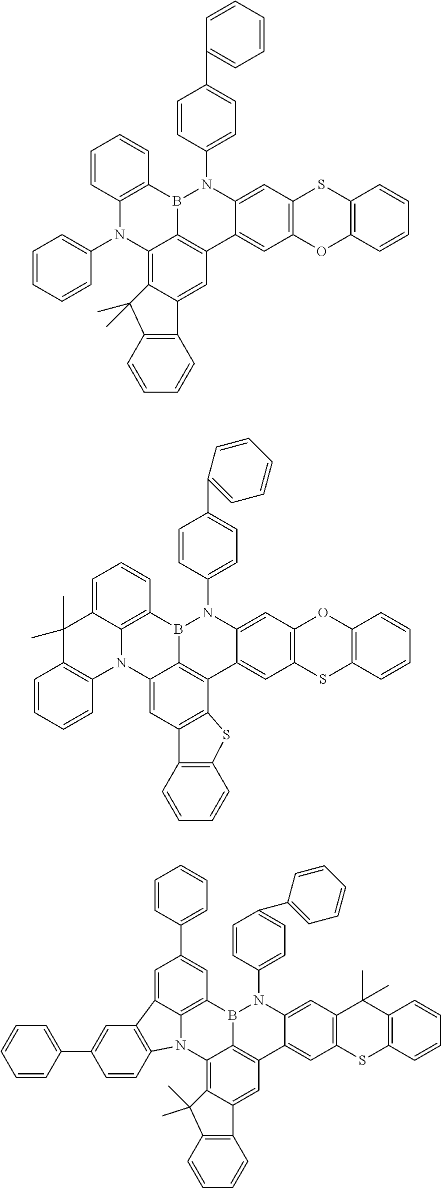 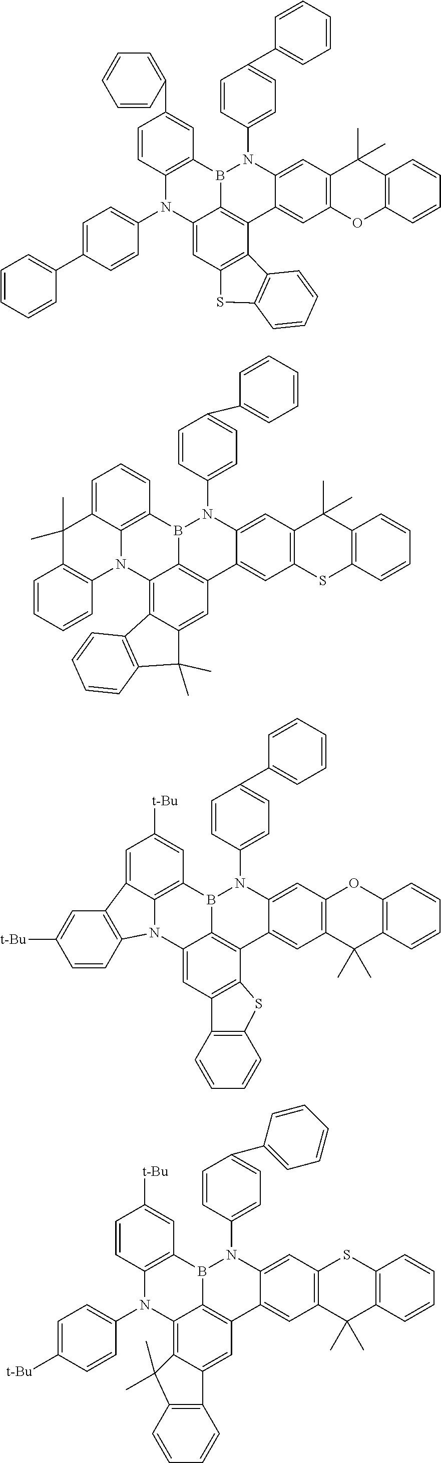 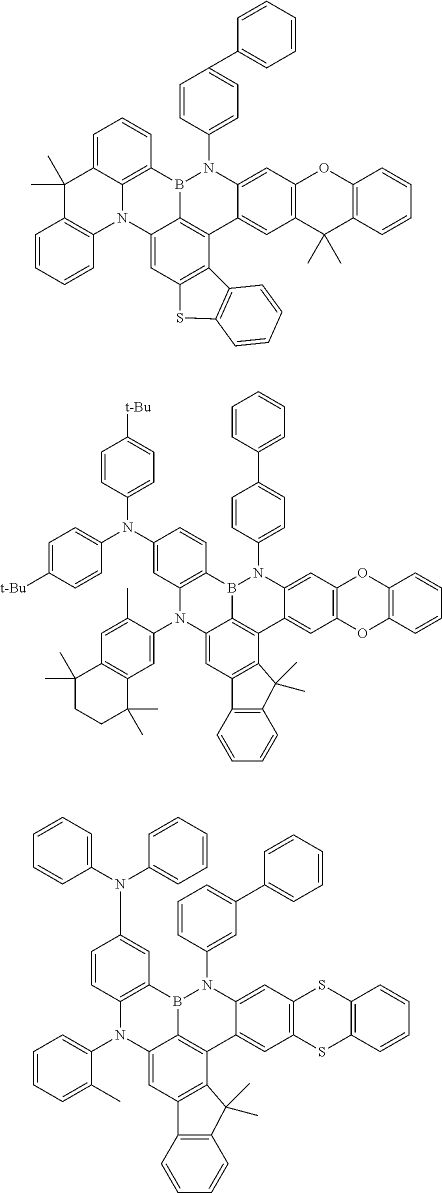 [SMILES: CC1(C)c2ccccc2Oc2cc3c(cc21)-c1c2c(cc4sc5ccccc5c14)N1c4ccccc4C(C)(C)c4cccc(c41)B2N3c1ccc(-c2ccccc2)cc1 ; Cc1cc2c(cc1N1c3cc(N(c4ccc(C(C)(C)C)cc4)c4ccc(C(C)(C)C)cc4)ccc3B3c4c1cc1c(c4-c4cc5c(cc4N3c3ccc(-c4ccccc4)cc3)Oc3ccccc3O5)C(C)(C)c3ccccc3-1)C(C)(C)CCC2(C)C ; Cc1ccccc1N1c2ccc(N(c3ccccc3)c3ccccc3)cc2B2c3c1cc1c(c3-c3cc4c(cc3N2c2cccc(-c3ccccc3)c2)Sc2ccccc2S4)C(C)(C)c2ccccc2-1] 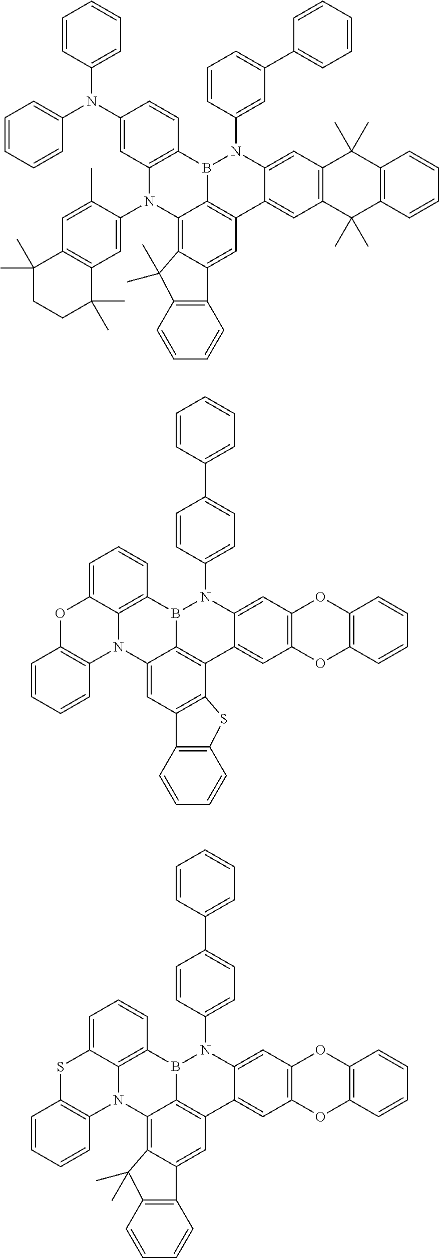 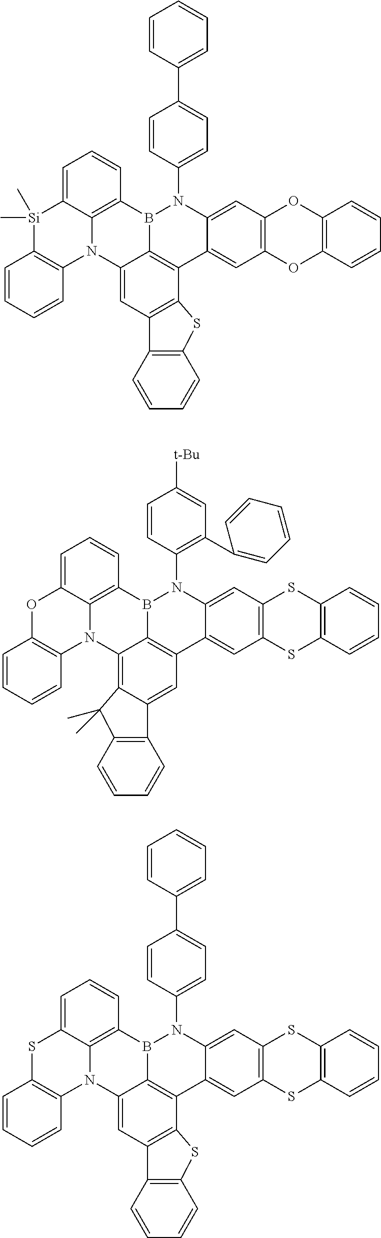 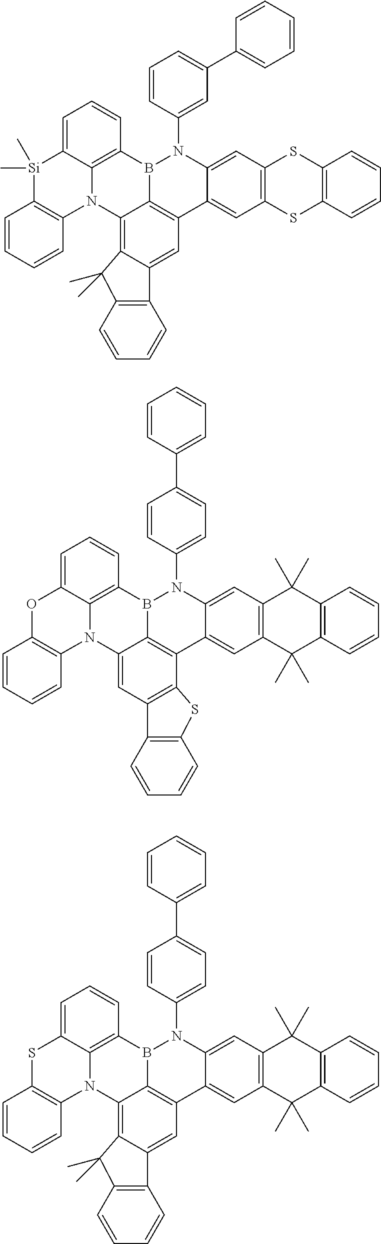 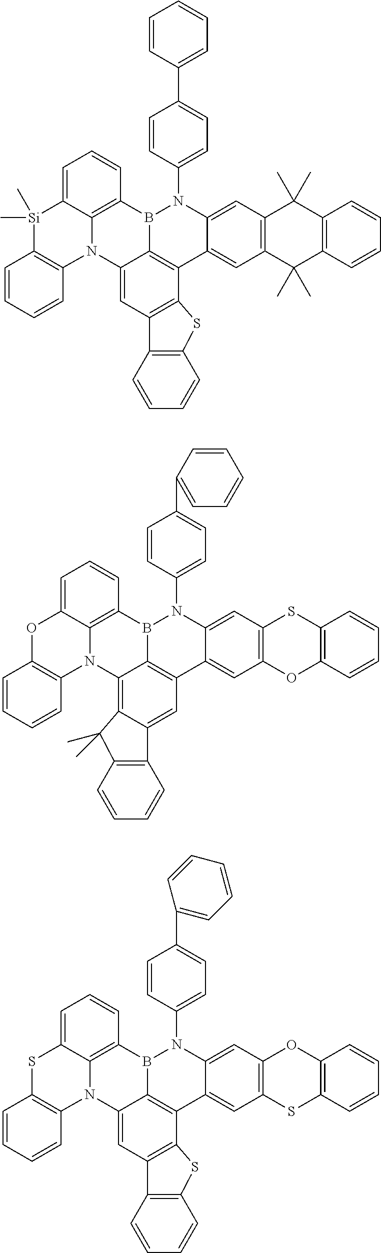 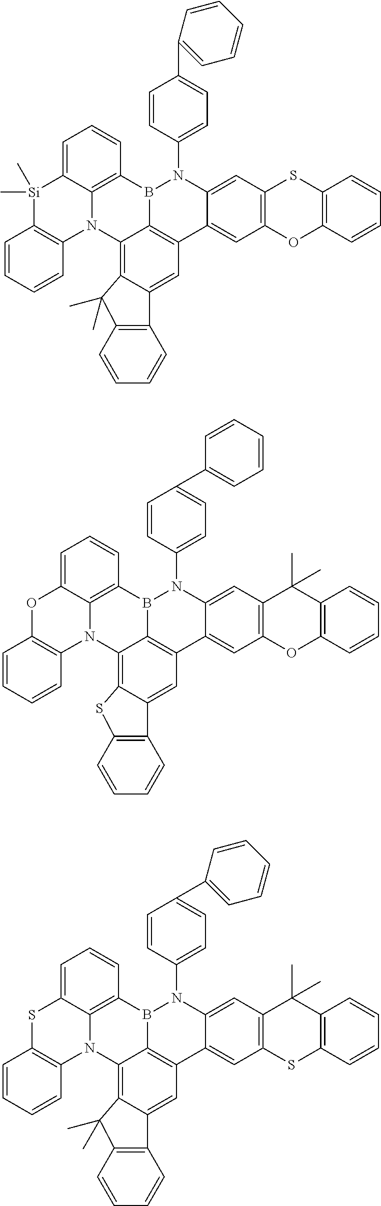 [SMILES: CC1(C)c2ccccc2-c2cc3c4c(c21)N1c2ccccc2[Si](C)(C)c2cccc(c21)B4N(c1ccc(-c2ccccc2)cc1)c1cc2c(cc1-3)Oc1ccccc1S2 ; CC1(C)c2ccccc2Oc2cc3c(cc21)N(c1ccc(-c2ccccc2)cc1)B1c2cccc4c2N(c2ccccc2O4)c2c1c-3cc1c2sc2ccccc21 ; CC1(C)c2ccccc2Sc2cc3c(cc21)N(c1ccc(-c2ccccc2)cc1)B1c2cccc4c2N(c2ccccc2S4)c2c1c-3cc1c2C(C)(C)c2ccccc2-1] 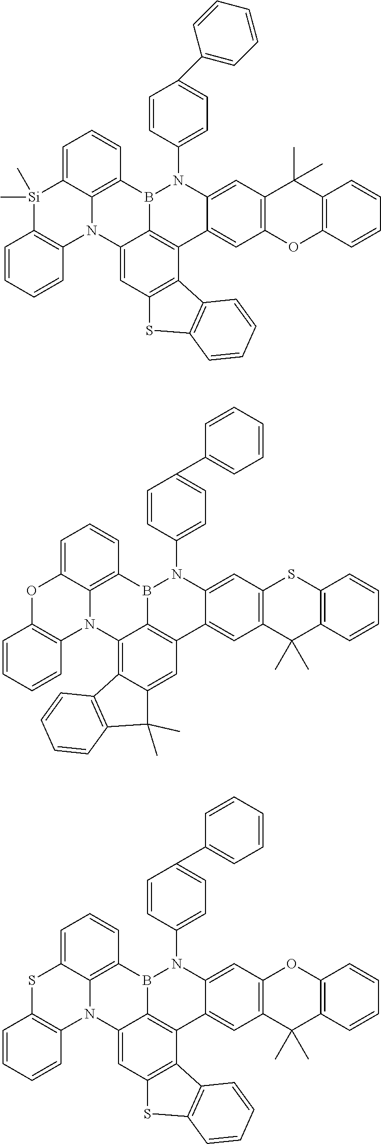 [SMILES: CC1(C)c2ccccc2Oc2cc3c(cc21)N(c1ccc(-c2ccccc2)cc1)B1c2cccc4c2N(c2ccccc2[Si]4(C)C)c2cc4sc5ccccc5c4c-3c21 ; CC1(C)c2ccccc2Sc2cc3c(cc21)-c1cc2c(c4c1B(c1cccc5c1N4c1ccccc1O5)N3c1ccc(-c3ccccc3)cc1)-c1ccccc1C2(C)C ; CC1(C)c2ccccc2Oc2cc3c(cc21)-c1c2c(cc4sc5ccccc5c14)N1c4ccccc4Sc4cccc(c41)B2N3c1ccc(-c2ccccc2)cc1] 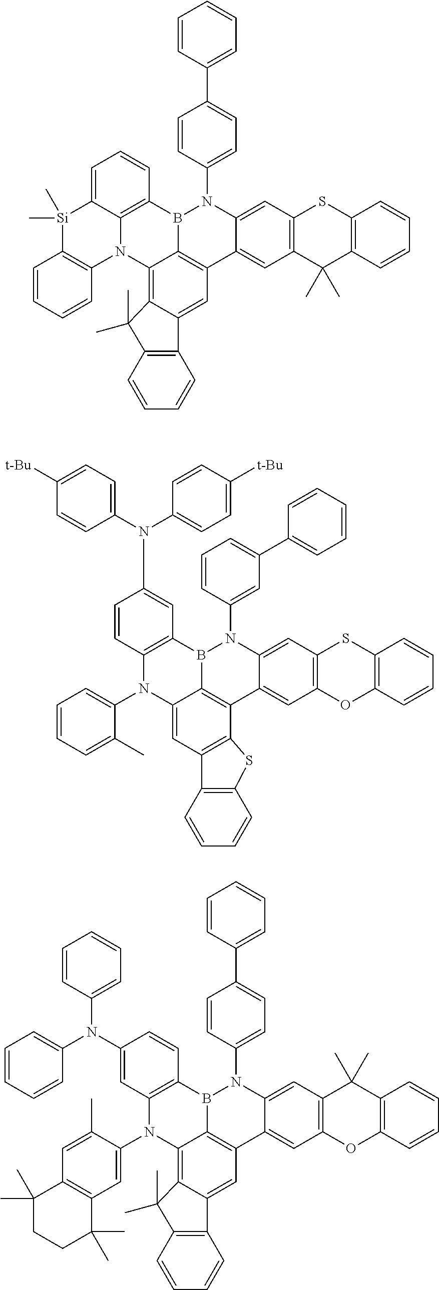 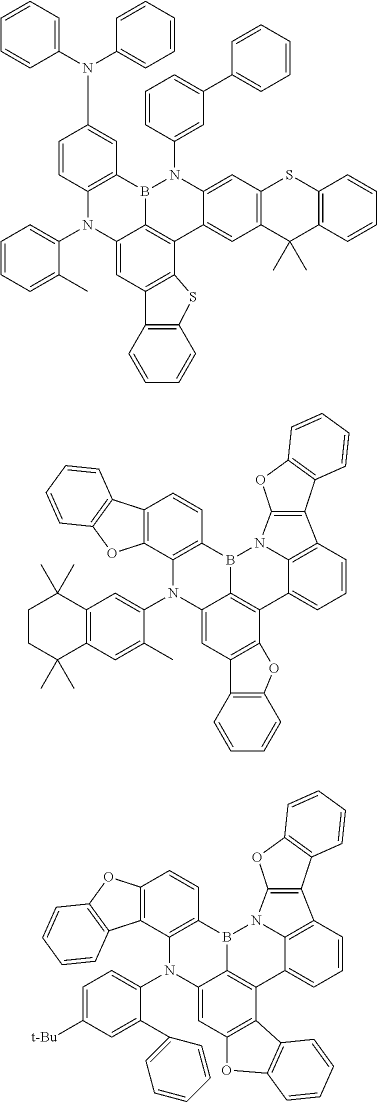 [SMILES: Cc1ccccc1N1c2ccc(N(c3ccccc3)c3ccccc3)cc2B2c3c1cc1c(sc4ccccc41)c3-c1cc3c(cc1N2c1cccc(-c2ccccc2)c1)Sc1ccccc1C3(C)C ; Cc1cc2c(cc1N1c3cc4c(oc5ccccc54)c4c3B(c3ccc5c(oc6ccccc65)c31)n1c3oc5ccccc5c3c3cccc-4c31)C(C)(C)CCC2(C)C ; CC(C)(C)c1ccc(N2c3cc4oc5ccccc5c4c4c3B(c3ccc5oc6ccccc6c5c32)n2c3oc5ccccc5c3c3cccc-4c32)c(-c2ccccc2)c1] 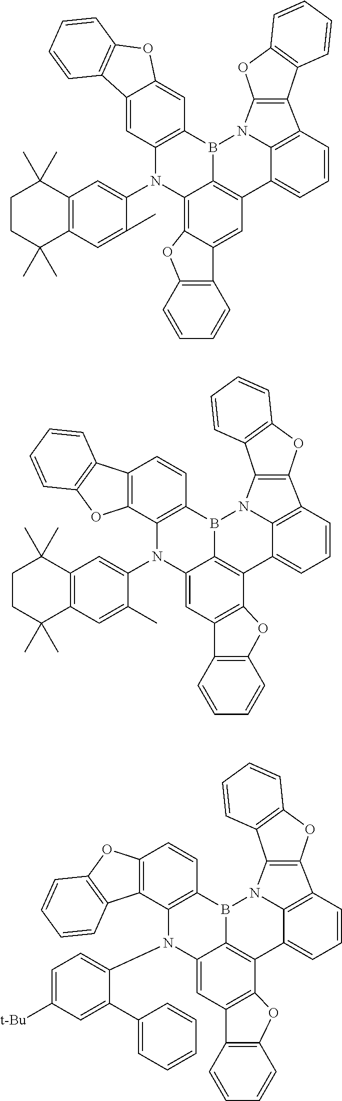 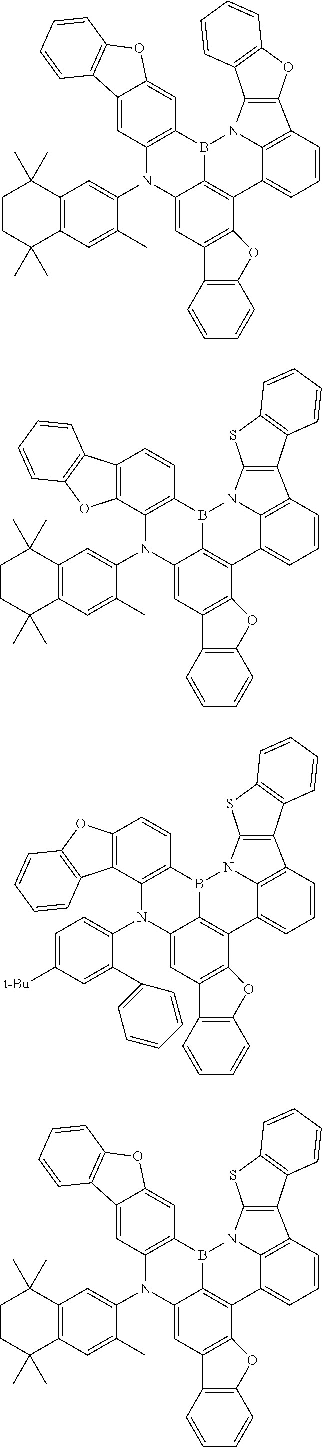 [SMILES: Cc1cc2c(cc1N1c3cc4c(cc3B3c5c1cc1c(oc6ccccc61)c5-c1cccc5c6oc7ccccc7c6n3c15)oc1ccccc14)C(C)(C)CCC2(C)C ; Cc1cc2c(cc1N1c3cc4c(oc5ccccc54)c4c3B(c3ccc5c(oc6ccccc65)c31)n1c3sc5ccccc5c3c3cccc-4c31)C(C)(C)CCC2(C)C ; CC(C)(C)c1ccc(N2c3cc4c(oc5ccccc54)c4c3B(c3ccc5oc6ccccc6c5c32)n2c3sc5ccccc5c3c3cccc-4c32)c(-c2ccccc2)c1 ; Cc1cc2c(cc1N1c3cc4c(cc3B3c5c1cc1c(oc6ccccc61)c5-c1cccc5c6c7ccccc7sc6n3c15)oc1ccccc14)C(C)(C)CCC2(C)C] 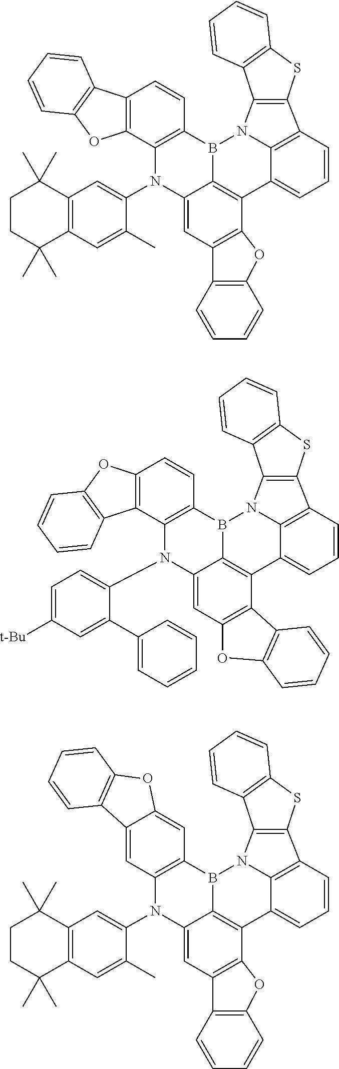 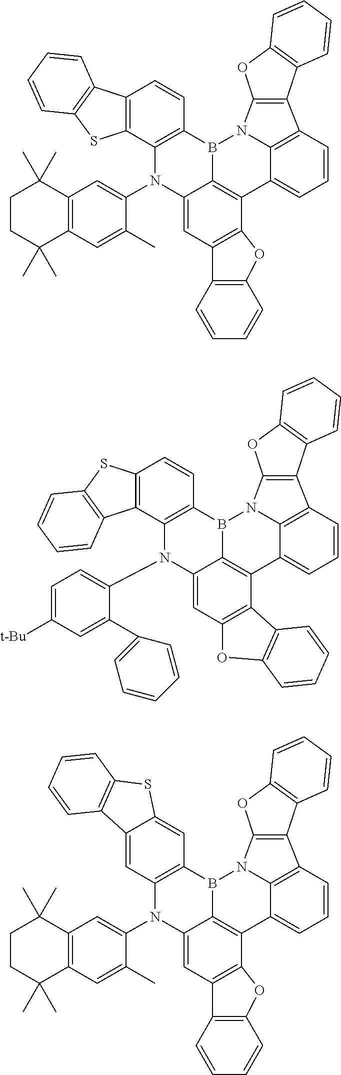 [SMILES: Cc1cc2c(cc1N1c3cc4c(oc5ccccc54)c4c3B(c3ccc5c(sc6ccccc65)c31)n1c3oc5ccccc5c3c3cccc-4c31)C(C)(C)CCC2(C)C ; CC(C)(C)c1ccc(N2c3cc4oc5ccccc5c4c4c3B(c3ccc5sc6ccccc6c5c32)n2c3oc5ccccc5c3c3cccc-4c32)c(-c2ccccc2)c1 ; Cc1cc2c(cc1N1c3cc4c(cc3B3c5c1cc1c(oc6ccccc61)c5-c1cccc5c6c7ccccc7oc6n3c15)sc1ccccc14)C(C)(C)CCC2(C)C] 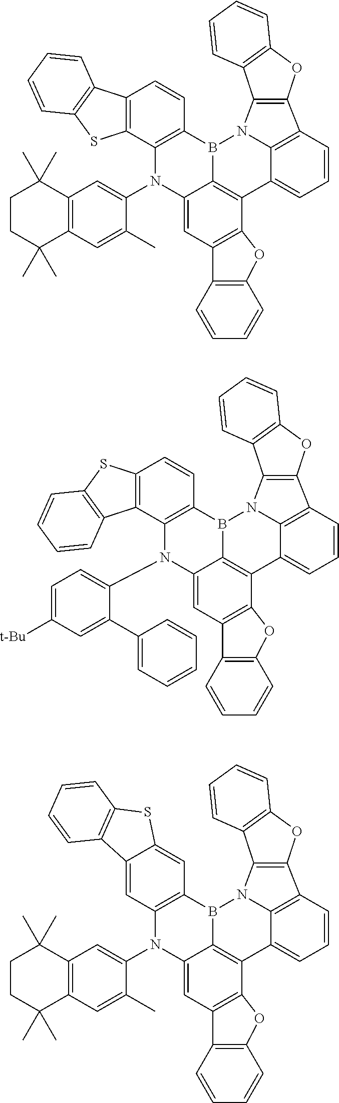 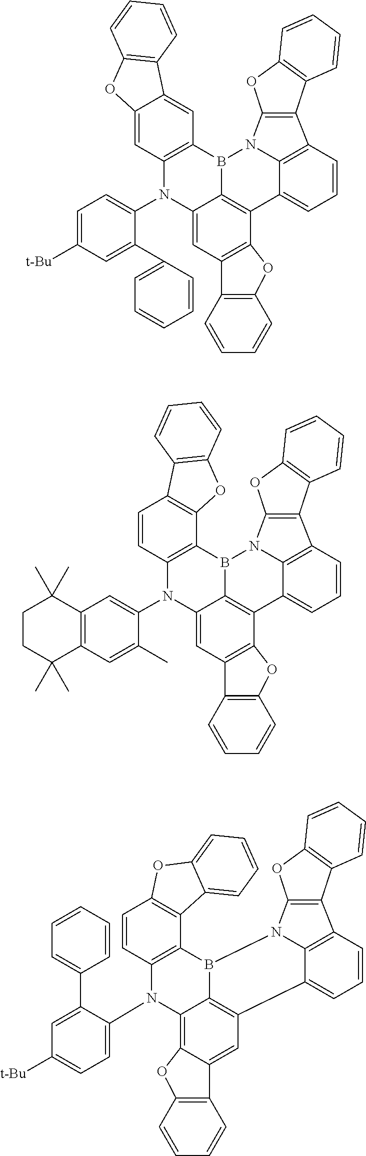 [SMILES: CC(C)(C)c1ccc(N2c3cc4oc5ccccc5c4cc3B3c4c2cc2c(oc5ccccc52)c4-c2cccc4c5c6ccccc6oc5n3c24)c(-c2ccccc2)c1 ; Cc1cc2c(cc1N1c3cc4c(oc5ccccc54)c4c3B(c3c1ccc1c3oc3ccccc31)n1c3oc5ccccc5c3c3cccc-4c31)C(C)(C)CCC2(C)C ; CC(C)(C)c1ccc(N2c3ccc4oc5ccccc5c4c3B3c4c(cc5c(oc6ccccc65)c42)-c2cccc4c5c6ccccc6oc5n3c24)c(-c2ccccc2)c1] 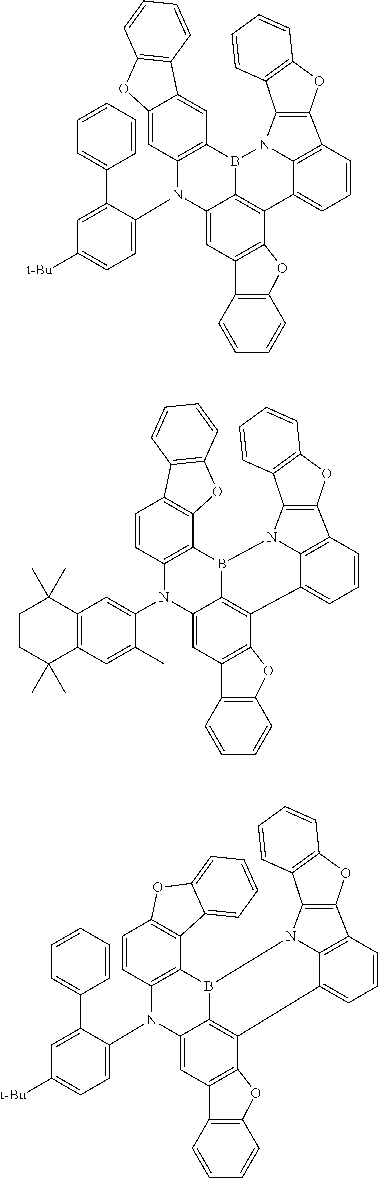 [SMILES: CC(C)(C)c1ccc(N2c3cc4oc5ccccc5c4cc3B3c4c2cc2c(oc5ccccc52)c4-c2cccc4c5oc6ccccc6c5n3c24)c(-c2ccccc2)c1 ; Cc1cc2c(cc1N1c3cc4c(oc5ccccc54)c4c3B(c3c1ccc1c3oc3ccccc31)n1c3c-4cccc3c3oc4ccccc4c31)C(C)(C)CCC2(C)C ; CC(C)(C)c1ccc(N2c3cc4c(oc5ccccc54)c4c3B(c3c2ccc2oc5ccccc5c32)n2c3c-4cccc3c3oc4ccccc4c32)c(-c2ccccc2)c1] 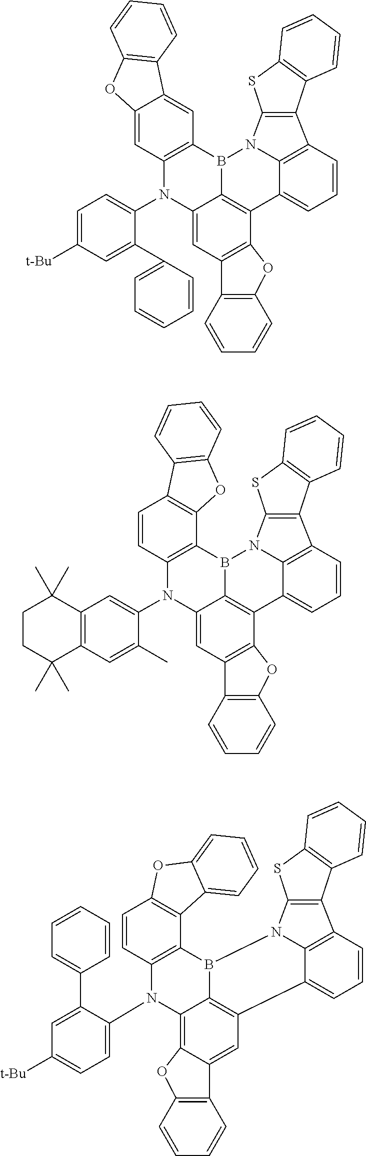 [SMILES: CC(C)(C)c1ccc(N2c3cc4oc5ccccc5c4cc3B3c4c2cc2c(oc5ccccc52)c4-c2cccc4c5c6ccccc6sc5n3c24)c(-c2ccccc2)c1 ; Cc1cc2c(cc1N1c3cc4c(oc5ccccc54)c4c3B(c3c1ccc1c3oc3ccccc31)n1c3sc5ccccc5c3c3cccc-4c31)C(C)(C)CCC2(C)C ; CC(C)(C)c1ccc(N2c3ccc4oc5ccccc5c4c3B3c4c(cc5c(oc6ccccc65)c42)-c2cccc4c5c6ccccc6sc5n3c24)c(-c2ccccc2)c1] 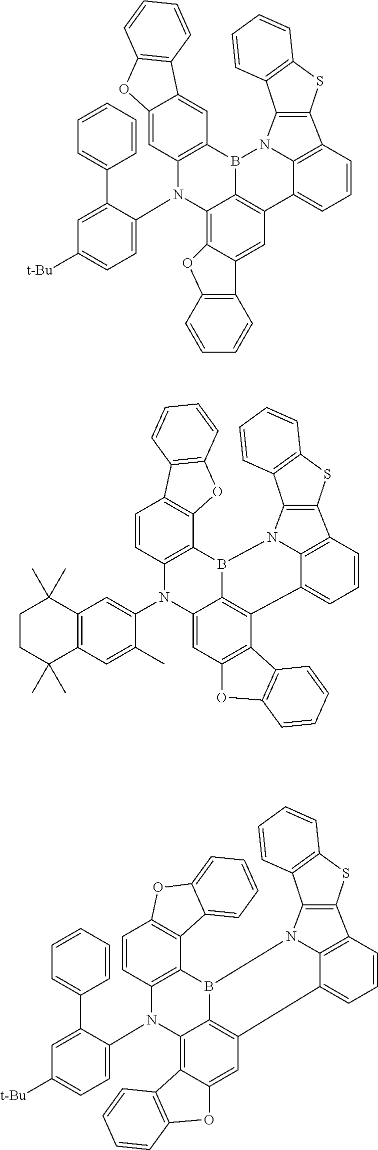 [SMILES: CC(C)(C)c1ccc(N2c3cc4oc5ccccc5c4cc3B3c4c(cc5c(oc6ccccc65)c42)-c2cccc4c5sc6ccccc6c5n3c24)c(-c2ccccc2)c1 ; Cc1cc2c(cc1N1c3cc4oc5ccccc5c4c4c3B(c3c1ccc1c3oc3ccccc31)n1c3c-4cccc3c3sc4ccccc4c31)C(C)(C)CCC2(C)C ; CC(C)(C)c1ccc(N2c3ccc4oc5ccccc5c4c3B3c4c(cc5oc6ccccc6c5c42)-c2cccc4c5sc6ccccc6c5n3c24)c(-c2ccccc2)c1] 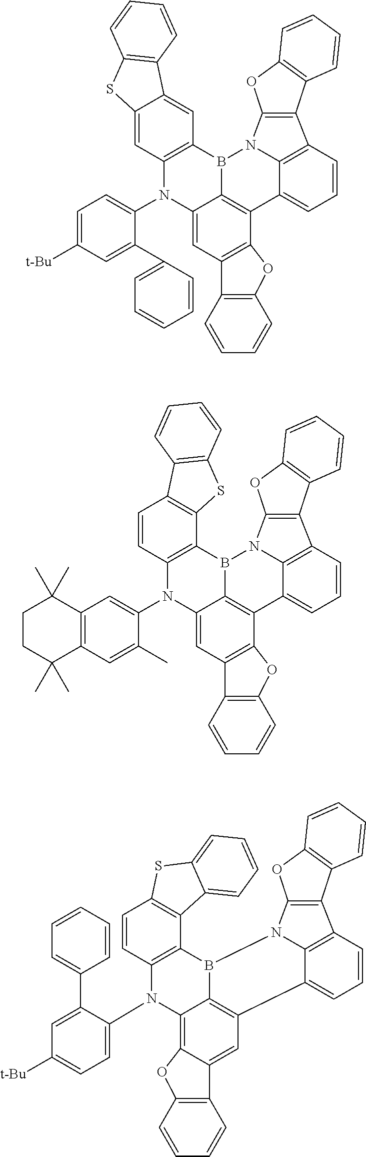 [SMILES: CC(C)(C)c1ccc(N2c3cc4sc5ccccc5c4cc3B3c4c2cc2c(oc5ccccc52)c4-c2cccc4c5c6ccccc6oc5n3c24)c(-c2ccccc2)c1 ; Cc1cc2c(cc1N1c3cc4c(oc5ccccc54)c4c3B(c3c1ccc1c3sc3ccccc31)n1c3oc5ccccc5c3c3cccc-4c31)C(C)(C)CCC2(C)C ; CC(C)(C)c1ccc(N2c3ccc4sc5ccccc5c4c3B3c4c(cc5c(oc6ccccc65)c42)-c2cccc4c5c6ccccc6oc5n3c24)c(-c2ccccc2)c1] 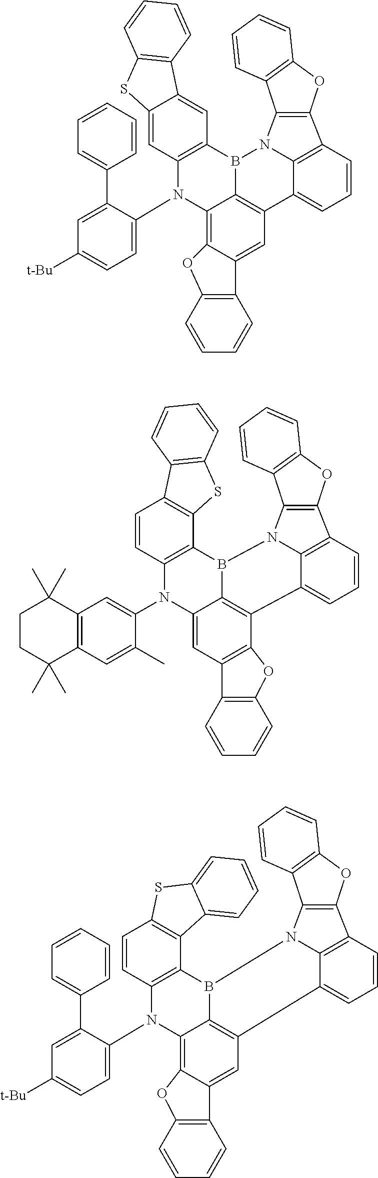 [SMILES: CC(C)(C)c1ccc(N2c3cc4sc5ccccc5c4cc3B3c4c(cc5c(oc6ccccc65)c42)-c2cccc4c5oc6ccccc6c5n3c24)c(-c2ccccc2)c1 ; Cc1cc2c(cc1N1c3cc4c(oc5ccccc54)c4c3B(c3c1ccc1c3sc3ccccc31)n1c3c-4cccc3c3oc4ccccc4c31)C(C)(C)CCC2(C)C ; CC(C)(C)c1ccc(N2c3ccc4sc5ccccc5c4c3B3c4c(cc5c(oc6ccccc65)c42)-c2cccc4c5oc6ccccc6c5n3c24)c(-c2ccccc2)c1] 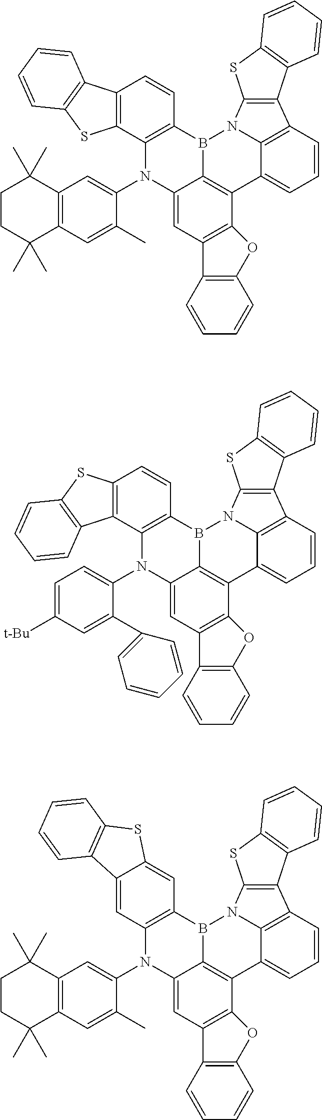 [SMILES: Cc1cc2c(cc1N1c3cc4c(oc5ccccc54)c4c3B(c3ccc5c(sc6ccccc65)c31)n1c3sc5ccccc5c3c3cccc-4c31)C(C)(C)CCC2(C)C ; CC(C)(C)c1ccc(N2c3cc4c(oc5ccccc54)c4c3B(c3ccc5sc6ccccc6c5c32)n2c3sc5ccccc5c3c3cccc-4c32)c(-c2ccccc2)c1 ; Cc1cc2c(cc1N1c3cc4c(cc3B3c5c1cc1c(oc6ccccc61)c5-c1cccc5c6c7ccccc7sc6n3c15)sc1ccccc14)C(C)(C)CCC2(C)C] 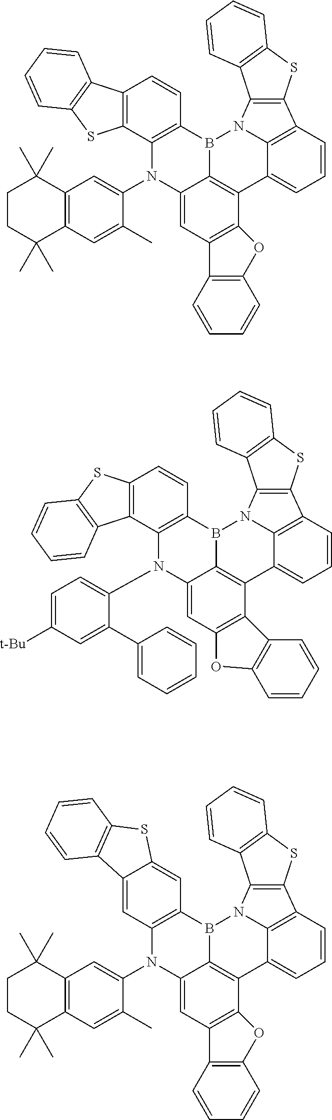 [SMILES: Cc1cc2c(cc1N1c3cc4c(oc5ccccc54)c4c3B(c3ccc5c(sc6ccccc65)c31)n1c3c-4cccc3c3sc4ccccc4c31)C(C)(C)CCC2(C)C ; CC(C)(C)c1ccc(N2c3cc4oc5ccccc5c4c4c3B(c3ccc5sc6ccccc6c5c32)n2c3c-4cccc3c3sc4ccccc4c32)c(-c2ccccc2)c1 ; Cc1cc2c(cc1N1c3cc4c(cc3B3c5c1cc1c(oc6ccccc61)c5-c1cccc5c6sc7ccccc7c6n3c15)sc1ccccc14)C(C)(C)CCC2(C)C] 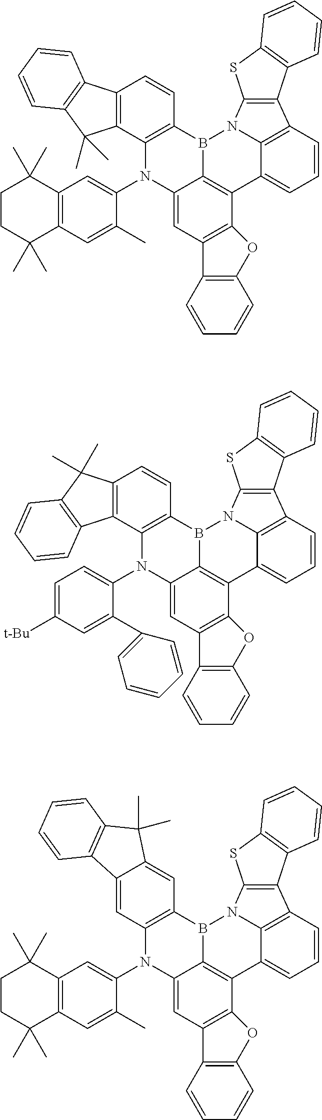 [SMILES: Cc1cc2c(cc1N1c3cc4c(oc5ccccc54)c4c3B(c3ccc5c(c31)C(C)(C)c1ccccc1-5)n1c3sc5ccccc5c3c3cccc-4c31)C(C)(C)CCC2(C)C ; CC(C)(C)c1ccc(N2c3cc4c(oc5ccccc54)c4c3B(c3ccc5c(c32)-c2ccccc2C5(C)C)n2c3sc5ccccc5c3c3cccc-4c32)c(-c2ccccc2)c1 ; Cc1cc2c(cc1N1c3cc4c(cc3B3c5c1cc1c(oc6ccccc61)c5-c1cccc5c6c7ccccc7sc6n3c15)C(C)(C)c1ccccc1-4)C(C)(C)CCC2(C)C] 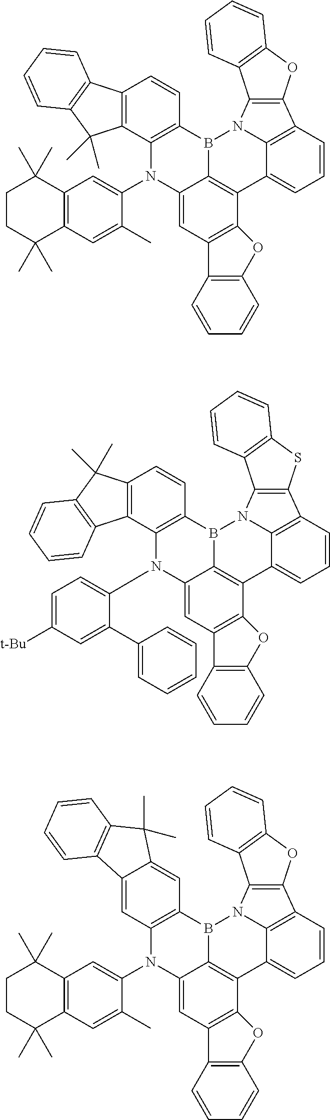 [SMILES: Cc1cc2c(cc1N1c3cc4c(oc5ccccc54)c4c3B(c3ccc5c(c31)C(C)(C)c1ccccc1-5)n1c3c-4cccc3c3oc4ccccc4c31)C(C)(C)CCC2(C)C ; CC(C)(C)c1ccc(N2c3cc4c(oc5ccccc54)c4c3B(c3ccc5c(c32)-c2ccccc2C5(C)C)n2c3c-4cccc3c3sc4ccccc4c32)c(-c2ccccc2)c1 ; Cc1cc2c(cc1N1c3cc4c(cc3B3c5c1cc1c(oc6ccccc61)c5-c1cccc5c6oc7ccccc7c6n3c15)C(C)(C)c1ccccc1-4)C(C)(C)CCC2(C)C] 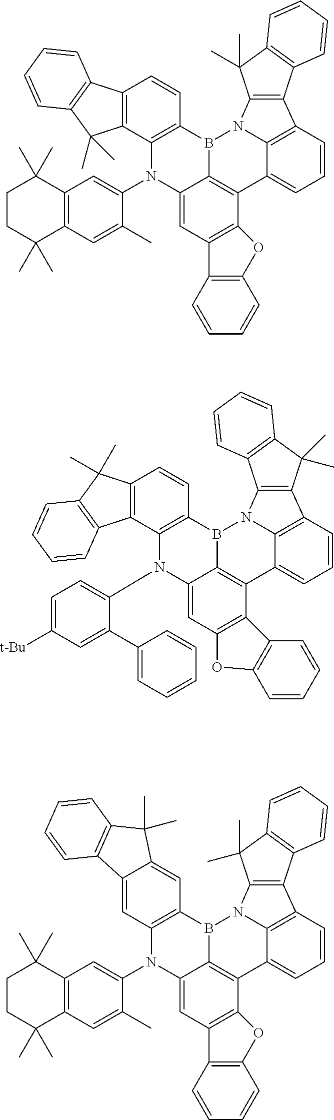 [SMILES: Cc1cc2c(cc1N1c3cc4c(oc5ccccc54)c4c3B(c3ccc5c(c31)C(C)(C)c1ccccc1-5)n1c3c(c5cccc-4c51)-c1ccccc1C3(C)C)C(C)(C)CCC2(C)C ; CC(C)(C)c1ccc(N2c3cc4oc5ccccc5c4c4c3B(c3ccc5c(c32)-c2ccccc2C5(C)C)n2c3c(c5cccc-4c52)C(C)(C)c2ccccc2-3)c(-c2ccccc2)c1 ; Cc1cc2c(cc1N1c3cc4c(cc3B3c5c1cc1c(oc6ccccc61)c5-c1cccc5c6c(n3c15)C(C)(C)c1ccccc1-6)C(C)(C)c1ccccc1-4)C(C)(C)CCC2(C)C] 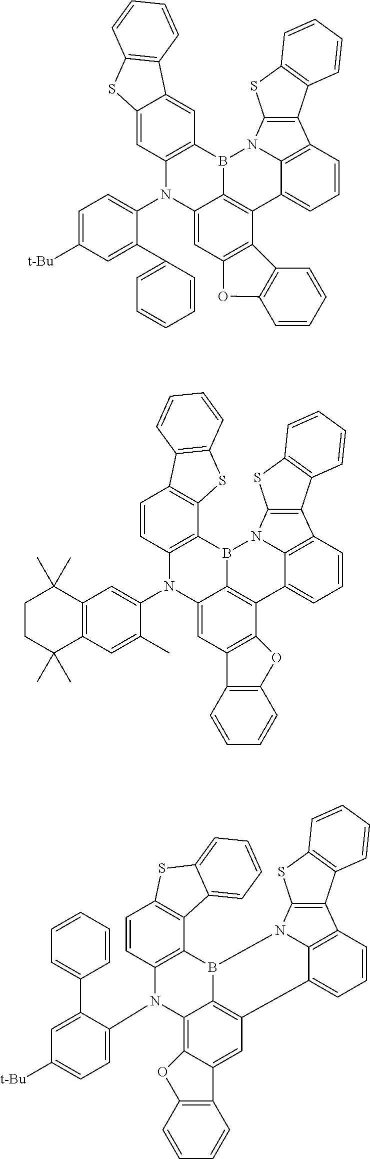 [SMILES: CC(C)(C)c1ccc(N2c3cc4sc5ccccc5c4cc3B3c4c2cc2oc5ccccc5c2c4-c2cccc4c5c6ccccc6sc5n3c24)c(-c2ccccc2)c1 ; Cc1cc2c(cc1N1c3cc4c(oc5ccccc54)c4c3B(c3c1ccc1c3sc3ccccc31)n1c3sc5ccccc5c3c3cccc-4c31)C(C)(C)CCC2(C)C ; CC(C)(C)c1ccc(N2c3ccc4sc5ccccc5c4c3B3c4c(cc5c(oc6ccccc65)c42)-c2cccc4c5c6ccccc6sc5n3c24)c(-c2ccccc2)c1] 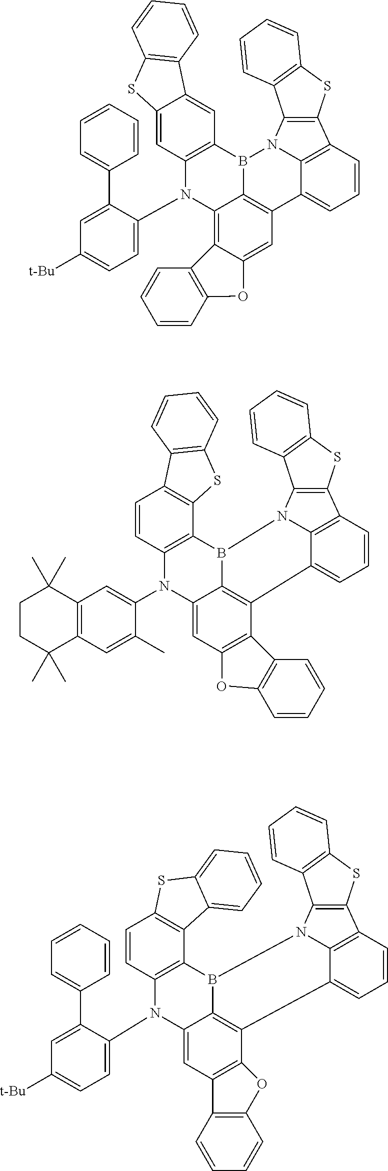 [SMILES: CC(C)(C)c1ccc(N2c3cc4sc5ccccc5c4cc3B3c4c(cc5oc6ccccc6c5c42)-c2cccc4c5sc6ccccc6c5n3c24)c(-c2ccccc2)c1 ; Cc1cc2c(cc1N1c3cc4oc5ccccc5c4c4c3B(c3c1ccc1c3sc3ccccc31)n1c3c-4cccc3c3sc4ccccc4c31)C(C)(C)CCC2(C)C ; CC(C)(C)c1ccc(N2c3cc4c(oc5ccccc54)c4c3B(c3c2ccc2sc5ccccc5c32)n2c3c-4cccc3c3sc4ccccc4c32)c(-c2ccccc2)c1] 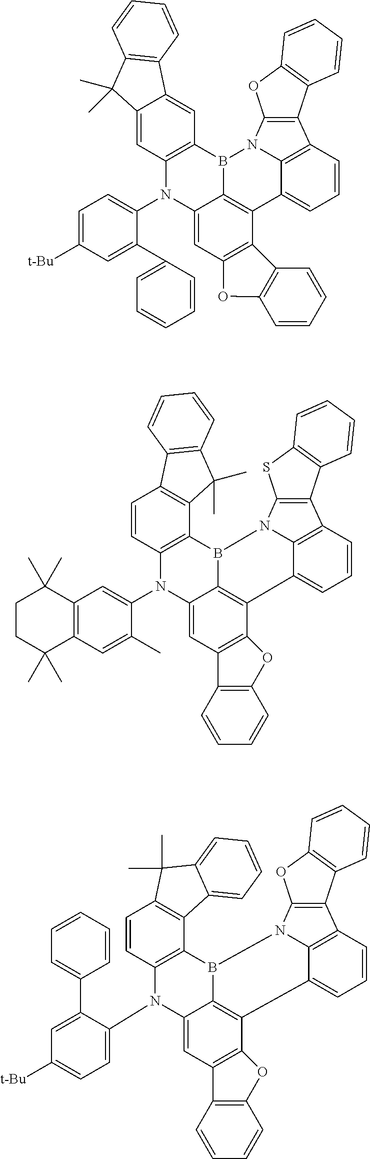 [SMILES: CC(C)(C)c1ccc(N2c3cc4c(cc3B3c5c2cc2oc6ccccc6c2c5-c2cccc5c6c7ccccc7oc6n3c25)-c2ccccc2C4(C)C)c(-c2ccccc2)c1 ; Cc1cc2c(cc1N1c3ccc4c(c3B3c5c1cc1c(oc6ccccc61)c5-c1cccc5c6c7ccccc7sc6n3c15)C(C)(C)c1ccccc1-4)C(C)(C)CCC2(C)C ; CC(C)(C)c1ccc(N2c3ccc4c(c3B3c5c2cc2c(oc6ccccc62)c5-c2cccc5c6c7ccccc7oc6n3c25)-c2ccccc2C4(C)C)c(-c2ccccc2)c1] 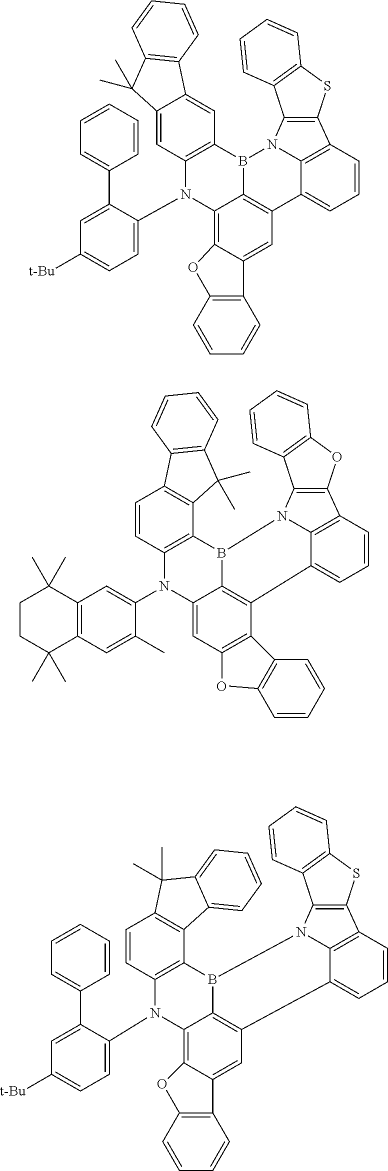 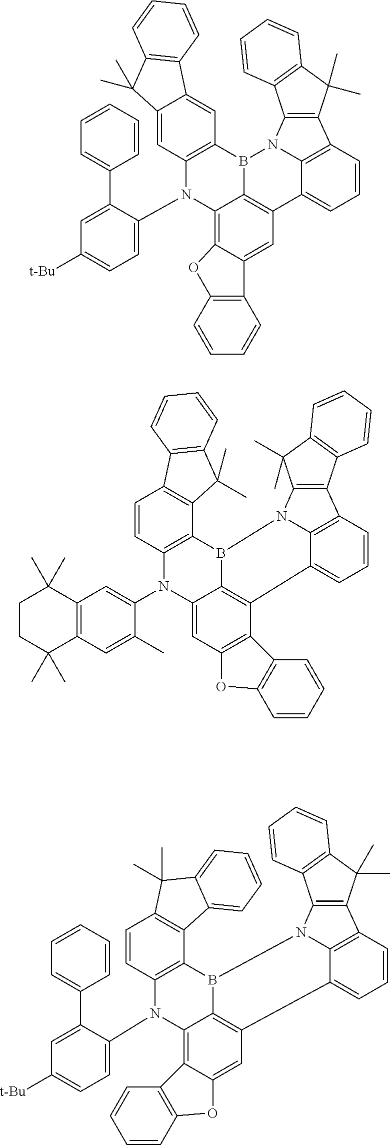 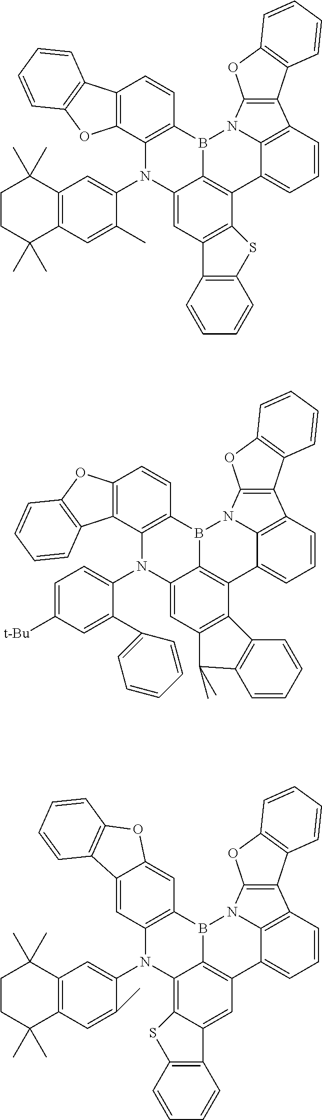 [SMILES: Cc1cc2c(cc1N1c3cc4c(sc5ccccc54)c4c3B(c3ccc5c(oc6ccccc65)c31)n1c3oc5ccccc5c3c3cccc-4c31)C(C)(C)CCC2(C)C ; CC(C)(C)c1ccc(N2c3cc4c(c5c3B(c3ccc6oc7ccccc7c6c32)n2c3oc6ccccc6c3c3cccc-5c32)-c2ccccc2C4(C)C)c(-c2ccccc2)c1 ; Cc1cc2c(cc1N1c3cc4c(cc3B3c5c(cc6c(sc7ccccc76)c51)-c1cccc5c6c7ccccc7oc6n3c15)oc1ccccc14)C(C)(C)CCC2(C)C] 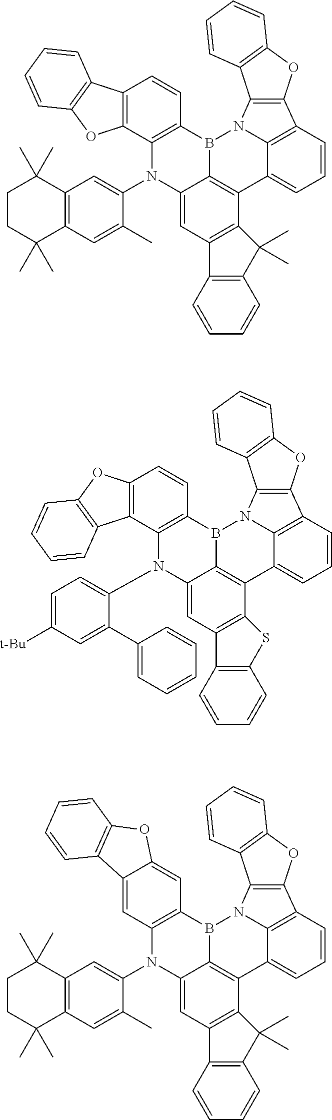 [SMILES: Cc1cc2c(cc1N1c3cc4c(c5c3B(c3ccc6c(oc7ccccc76)c31)n1c3c-5cccc3c3oc5ccccc5c31)C(C)(C)c1ccccc1-4)C(C)(C)CCC2(C)C ; CC(C)(C)c1ccc(N2c3cc4c(sc5ccccc54)c4c3B(c3ccc5oc6ccccc6c5c32)n2c3c-4cccc3c3oc4ccccc4c32)c(-c2ccccc2)c1 ; Cc1cc2c(cc1N1c3cc4c(cc3B3c5c1cc1c(c5-c5cccc6c7oc8ccccc8c7n3c56)C(C)(C)c3ccccc3-1)oc1ccccc14)C(C)(C)CCC2(C)C] 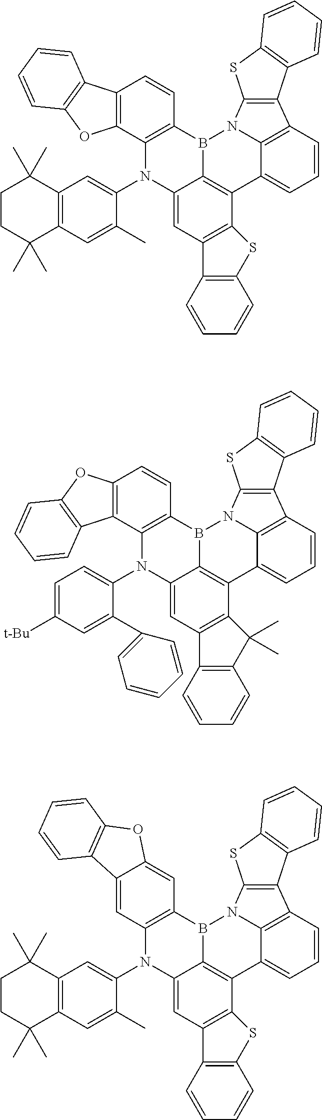 [SMILES: Cc1cc2c(cc1N1c3cc4c(sc5ccccc54)c4c3B(c3ccc5c(oc6ccccc65)c31)n1c3sc5ccccc5c3c3cccc-4c31)C(C)(C)CCC2(C)C ; CC(C)(C)c1ccc(N2c3cc4c(c5c3B(c3ccc6oc7ccccc7c6c32)n2c3sc6ccccc6c3c3cccc-5c32)C(C)(C)c2ccccc2-4)c(-c2ccccc2)c1 ; Cc1cc2c(cc1N1c3cc4c(cc3B3c5c1cc1c(sc6ccccc61)c5-c1cccc5c6c7ccccc7sc6n3c15)oc1ccccc14)C(C)(C)CCC2(C)C] 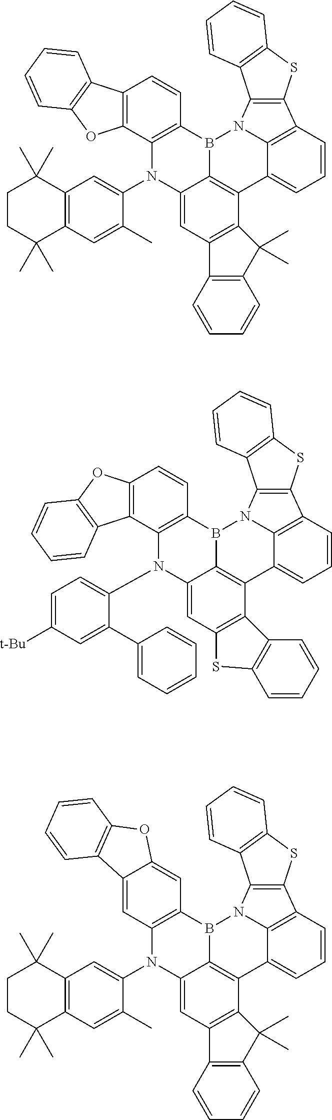 [SMILES: Cc1cc2c(cc1N1c3cc4c(c5c3B(c3ccc6c(oc7ccccc76)c31)n1c3c-5cccc3c3sc5ccccc5c31)C(C)(C)c1ccccc1-4)C(C)(C)CCC2(C)C ; CC(C)(C)c1ccc(N2c3cc4sc5ccccc5c4c4c3B(c3ccc5oc6ccccc6c5c32)n2c3c-4cccc3c3sc4ccccc4c32)c(-c2ccccc2)c1 ; Cc1cc2c(cc1N1c3cc4c(cc3B3c5c1cc1c(c5-c5cccc6c7sc8ccccc8c7n3c56)C(C)(C)c3ccccc3-1)oc1ccccc14)C(C)(C)CCC2(C)C] 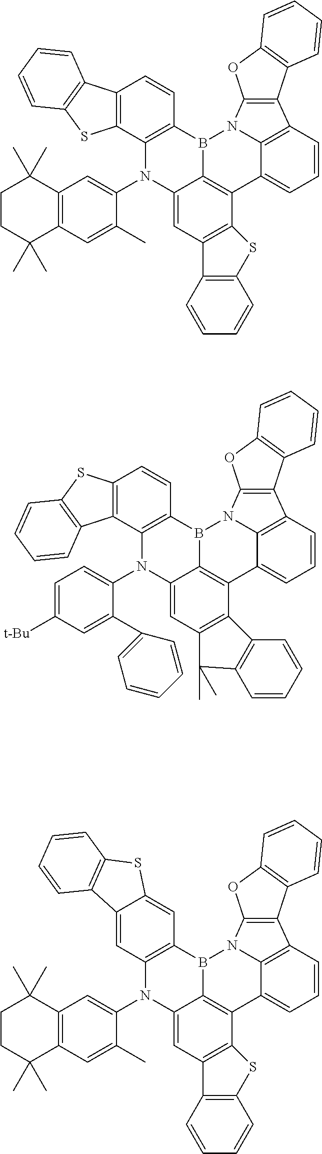 [SMILES: Cc1cc2c(cc1N1c3cc4c(sc5ccccc54)c4c3B(c3ccc5c(sc6ccccc65)c31)n1c3oc5ccccc5c3c3cccc-4c31)C(C)(C)CCC2(C)C ; CC(C)(C)c1ccc(N2c3cc4c(c5c3B(c3ccc6sc7ccccc7c6c32)n2c3oc6ccccc6c3c3cccc-5c32)-c2ccccc2C4(C)C)c(-c2ccccc2)c1 ; Cc1cc2c(cc1N1c3cc4c(cc3B3c5c1cc1c(sc6ccccc61)c5-c1cccc5c6c7ccccc7oc6n3c15)sc1ccccc14)C(C)(C)CCC2(C)C] 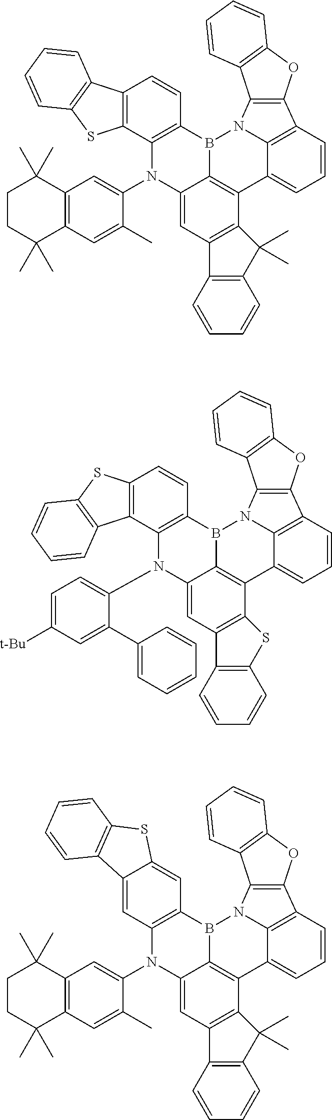 [SMILES: Cc1cc2c(cc1N1c3cc4c(c5c3B(c3ccc6c(sc7ccccc76)c31)n1c3c-5cccc3c3oc5ccccc5c31)C(C)(C)c1ccccc1-4)C(C)(C)CCC2(C)C ; CC(C)(C)c1ccc(N2c3cc4c(sc5ccccc54)c4c3B(c3ccc5sc6ccccc6c5c32)n2c3c-4cccc3c3oc4ccccc4c32)c(-c2ccccc2)c1 ; Cc1cc2c(cc1N1c3cc4c(cc3B3c5c1cc1c(c5-c5cccc6c7oc8ccccc8c7n3c56)C(C)(C)c3ccccc3-1)sc1ccccc14)C(C)(C)CCC2(C)C] 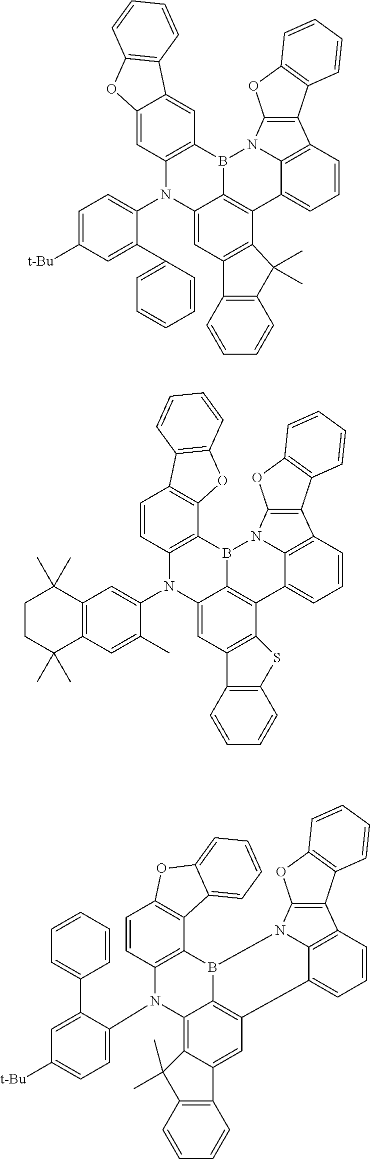 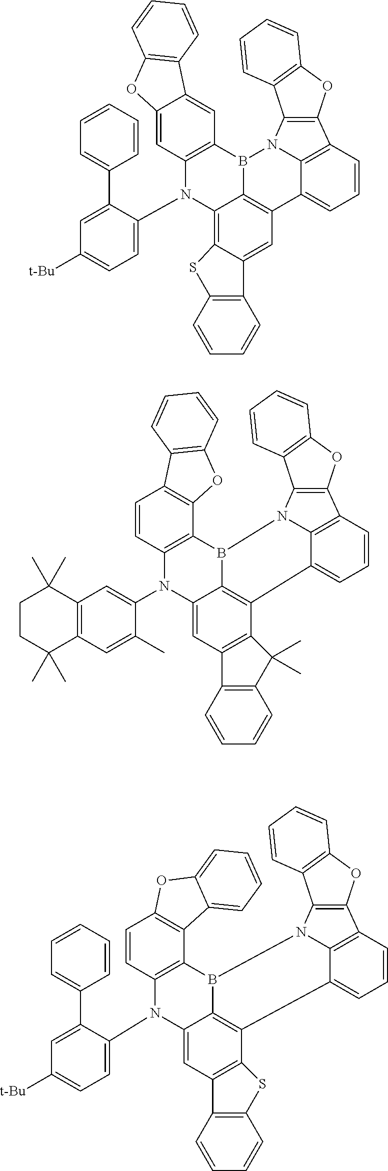 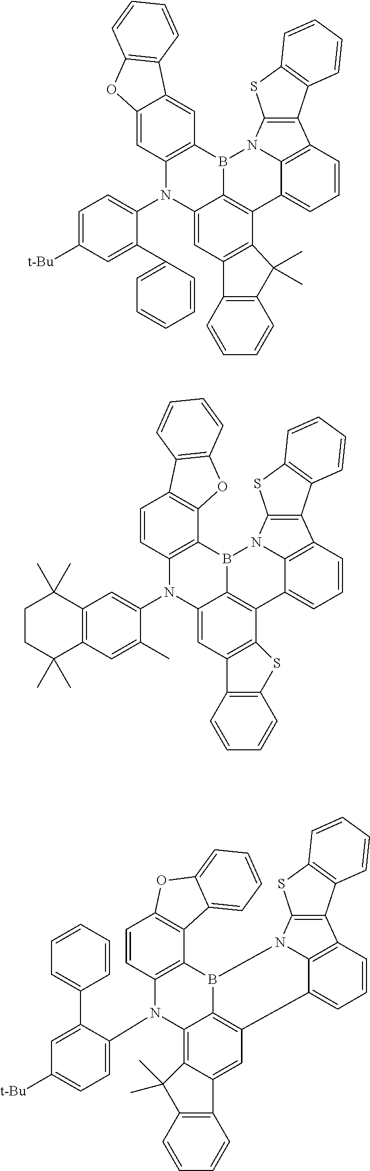 [SMILES: CC(C)(C)c1ccc(N2c3cc4oc5ccccc5c4cc3B3c4c2cc2c(c4-c4cccc5c6c7ccccc7sc6n3c45)C(C)(C)c3ccccc3-2)c(-c2ccccc2)c1 ; Cc1cc2c(cc1N1c3cc4c(sc5ccccc54)c4c3B(c3c1ccc1c3oc3ccccc31)n1c3sc5ccccc5c3c3cccc-4c31)C(C)(C)CCC2(C)C ; CC(C)(C)c1ccc(N2c3ccc4oc5ccccc5c4c3B3c4c(cc5c(c42)C(C)(C)c2ccccc2-5)-c2cccc4c5c6ccccc6sc5n3c24)c(-c2ccccc2)c1] 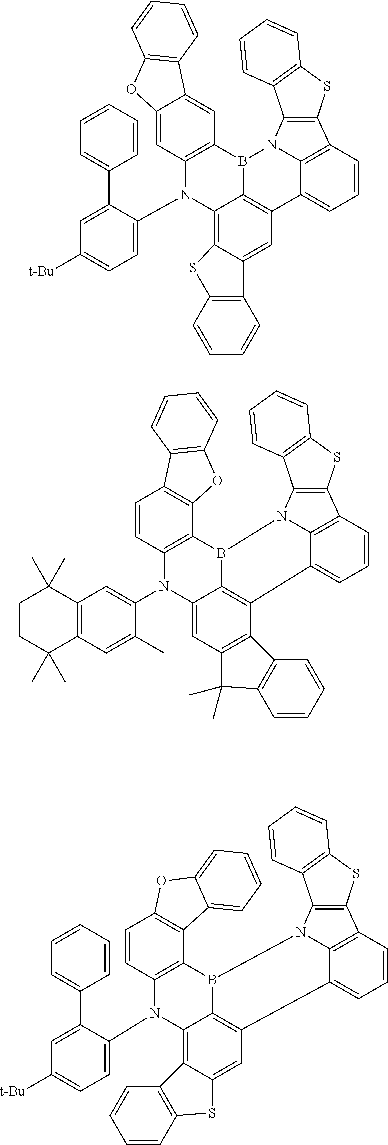 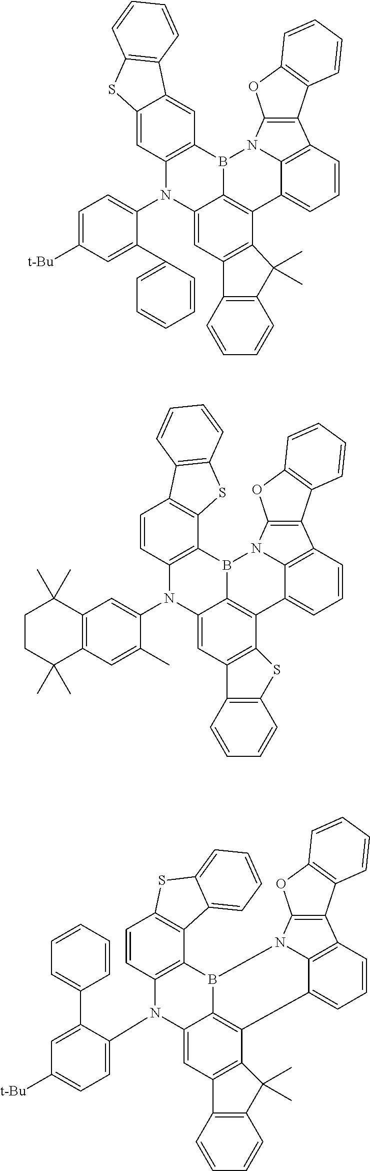 [SMILES: CC(C)(C)c1ccc(N2c3cc4sc5ccccc5c4cc3B3c4c2cc2c(c4-c4cccc5c6c7ccccc7oc6n3c45)C(C)(C)c3ccccc3-2)c(-c2ccccc2)c1 ; Cc1cc2c(cc1N1c3cc4c(sc5ccccc54)c4c3B(c3c1ccc1c3sc3ccccc31)n1c3oc5ccccc5c3c3cccc-4c31)C(C)(C)CCC2(C)C ; CC(C)(C)c1ccc(N2c3cc4c(c5c3B(c3c2ccc2sc6ccccc6c32)n2c3oc6ccccc6c3c3cccc-5c32)C(C)(C)c2ccccc2-4)c(-c2ccccc2)c1] 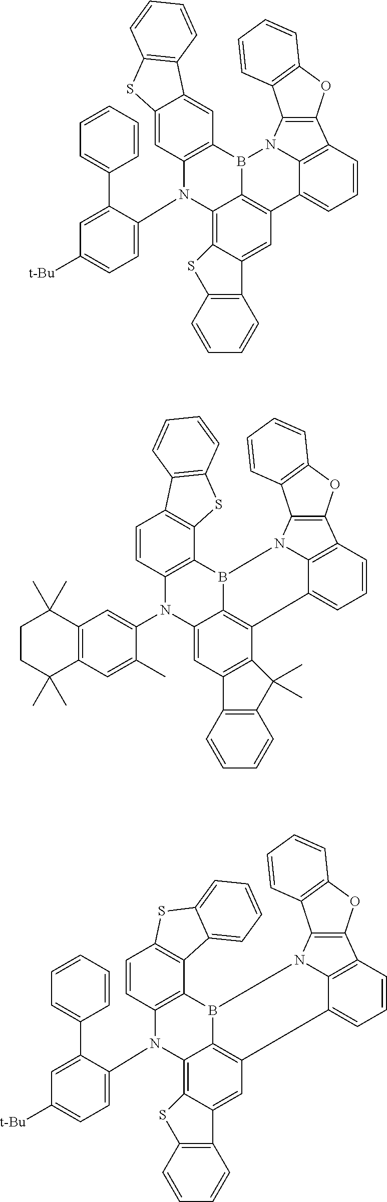 [SMILES: CC(C)(C)c1ccc(N2c3cc4sc5ccccc5c4cc3B3c4c(cc5c(sc6ccccc65)c42)-c2cccc4c5oc6ccccc6c5n3c24)c(-c2ccccc2)c1 ; Cc1cc2c(cc1N1c3cc4c(c5c3B(c3c1ccc1c3sc3ccccc31)n1c3c-5cccc3c3oc5ccccc5c31)C(C)(C)c1ccccc1-4)C(C)(C)CCC2(C)C ; CC(C)(C)c1ccc(N2c3ccc4sc5ccccc5c4c3B3c4c(cc5c(sc6ccccc65)c42)-c2cccc4c5oc6ccccc6c5n3c24)c(-c2ccccc2)c1] 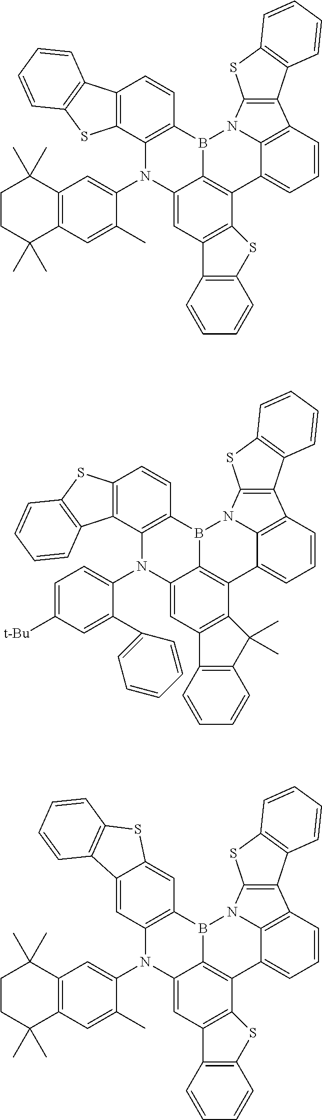 [SMILES: Cc1cc2c(cc1N1c3cc4c(sc5ccccc54)c4c3B(c3ccc5c(sc6ccccc65)c31)n1c3sc5ccccc5c3c3cccc-4c31)C(C)(C)CCC2(C)C ; CC(C)(C)c1ccc(N2c3cc4c(c5c3B(c3ccc6sc7ccccc7c6c32)n2c3sc6ccccc6c3c3cccc-5c32)C(C)(C)c2ccccc2-4)c(-c2ccccc2)c1 ; Cc1cc2c(cc1N1c3cc4c(cc3B3c5c1cc1c(sc6ccccc61)c5-c1cccc5c6c7ccccc7sc6n3c15)sc1ccccc14)C(C)(C)CCC2(C)C] 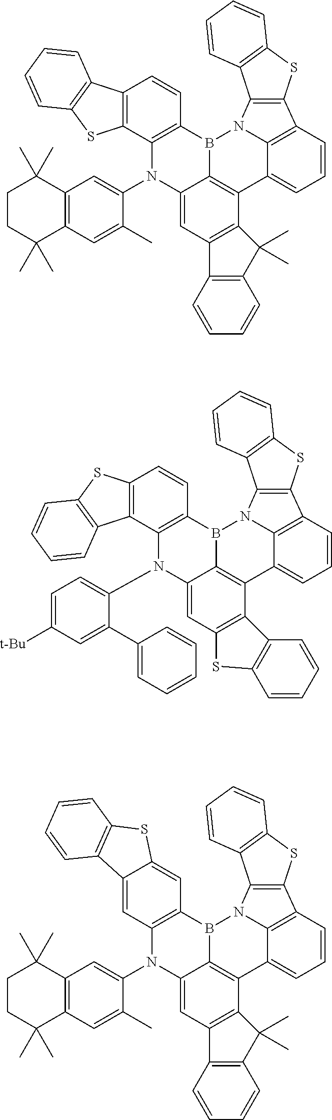 [SMILES: Cc1cc2c(cc1N1c3cc4c(c5c3B(c3ccc6c(sc7ccccc76)c31)n1c3c-5cccc3c3sc5ccccc5c31)C(C)(C)c1ccccc1-4)C(C)(C)CCC2(C)C ; CC(C)(C)c1ccc(N2c3cc4sc5ccccc5c4c4c3B(c3ccc5sc6ccccc6c5c32)n2c3c-4cccc3c3sc4ccccc4c32)c(-c2ccccc2)c1 ; Cc1cc2c(cc1N1c3cc4c(cc3B3c5c1cc1c(c5-c5cccc6c7sc8ccccc8c7n3c56)C(C)(C)c3ccccc3-1)sc1ccccc14)C(C)(C)CCC2(C)C] 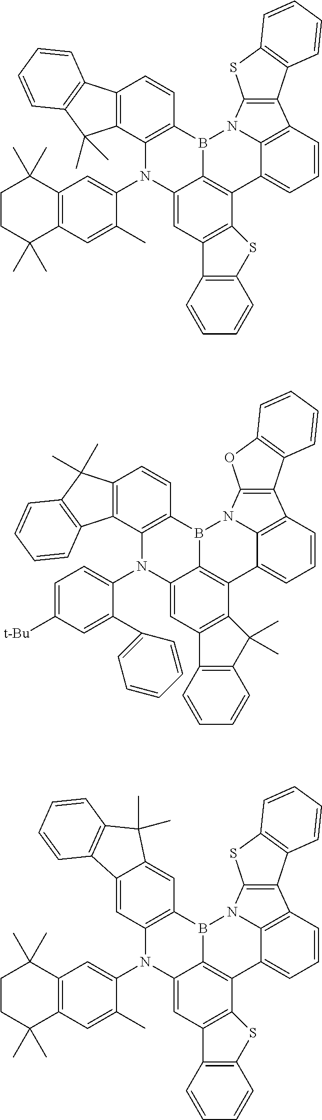 [SMILES: Cc1cc2c(cc1N1c3cc4c(sc5ccccc54)c4c3B(c3ccc5c(c31)C(C)(C)c1ccccc1-5)n1c3sc5ccccc5c3c3cccc-4c31)C(C)(C)CCC2(C)C ; CC(C)(C)c1ccc(N2c3cc4c(c5c3B(c3ccc6c(c32)-c2ccccc2C6(C)C)n2c3oc6ccccc6c3c3cccc-5c32)C(C)(C)c2ccccc2-4)c(-c2ccccc2)c1 ; Cc1cc2c(cc1N1c3cc4c(cc3B3c5c1cc1c(sc6ccccc61)c5-c1cccc5c6c7ccccc7sc6n3c15)C(C)(C)c1ccccc1-4)C(C)(C)CCC2(C)C] 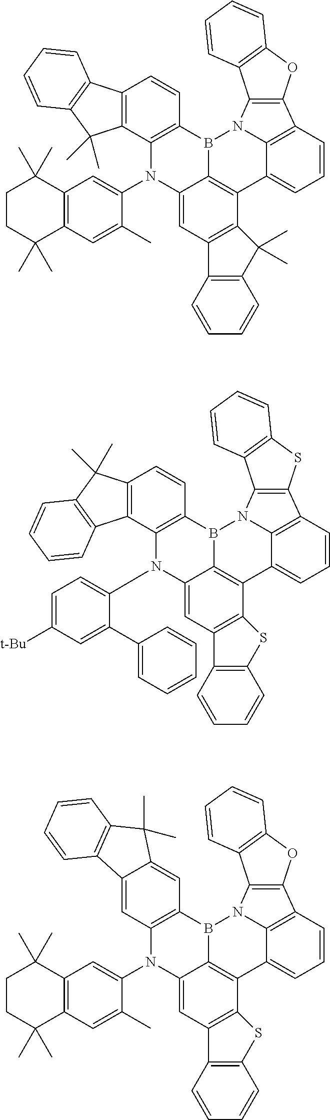 [SMILES: Cc1cc2c(cc1N1c3cc4c(c5c3B(c3ccc6c(c31)C(C)(C)c1ccccc1-6)n1c3c-5cccc3c3oc5ccccc5c31)C(C)(C)c1ccccc1-4)C(C)(C)CCC2(C)C ; CC(C)(C)c1ccc(N2c3cc4c(sc5ccccc54)c4c3B(c3ccc5c(c32)-c2ccccc2C5(C)C)n2c3c-4cccc3c3sc4ccccc4c32)c(-c2ccccc2)c1 ; Cc1cc2c(cc1N1c3cc4c(cc3B3c5c1cc1c(sc6ccccc61)c5-c1cccc5c6oc7ccccc7c6n3c15)C(C)(C)c1ccccc1-4)C(C)(C)CCC2(C)C] 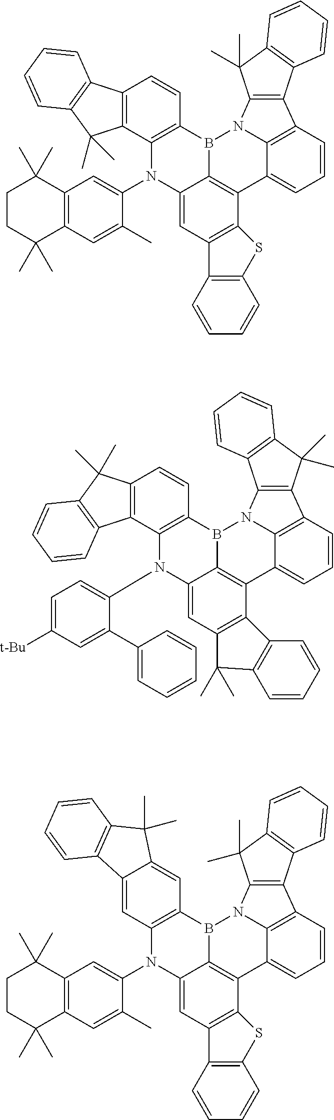 [SMILES: Cc1cc2c(cc1N1c3cc4c(sc5ccccc54)c4c3B(c3ccc5c(c31)C(C)(C)c1ccccc1-5)n1c3c(c5cccc-4c51)-c1ccccc1C3(C)C)C(C)(C)CCC2(C)C ; CC(C)(C)c1ccc(N2c3cc4c(c5c3B(c3ccc6c(c32)-c2ccccc2C6(C)C)n2c3c(c6cccc-5c62)C(C)(C)c2ccccc2-3)-c2ccccc2C4(C)C)c(-c2ccccc2)c1 ; Cc1cc2c(cc1N1c3cc4c(cc3B3c5c1cc1c(sc6ccccc61)c5-c1cccc5c6c(n3c15)C(C)(C)c1ccccc1-6)C(C)(C)c1ccccc1-4)C(C)(C)CCC2(C)C] 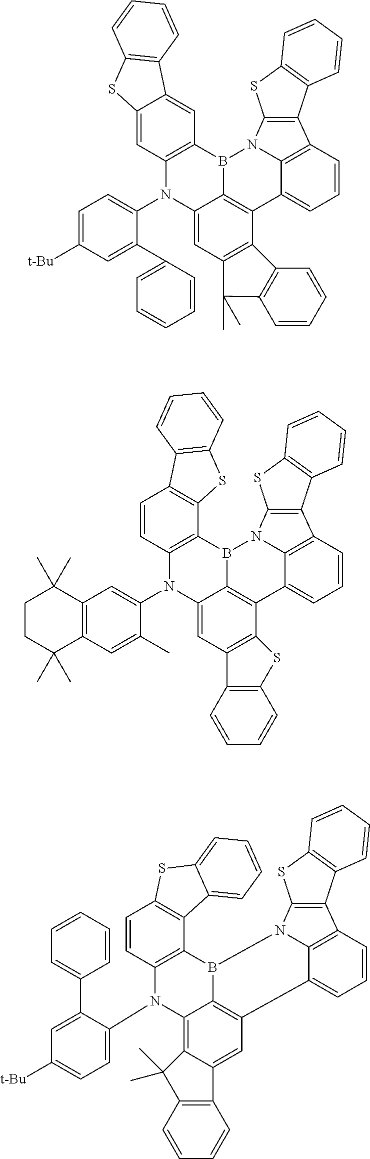 [SMILES: CC(C)(C)c1ccc(N2c3cc4sc5ccccc5c4cc3B3c4c2cc2c(c4-c4cccc5c6c7ccccc7sc6n3c45)-c3ccccc3C2(C)C)c(-c2ccccc2)c1 ; Cc1cc2c(cc1N1c3cc4c(sc5ccccc54)c4c3B(c3c1ccc1c3sc3ccccc31)n1c3sc5ccccc5c3c3cccc-4c31)C(C)(C)CCC2(C)C ; CC(C)(C)c1ccc(N2c3ccc4sc5ccccc5c4c3B3c4c(cc5c(c42)C(C)(C)c2ccccc2-5)-c2cccc4c5c6ccccc6sc5n3c24)c(-c2ccccc2)c1] 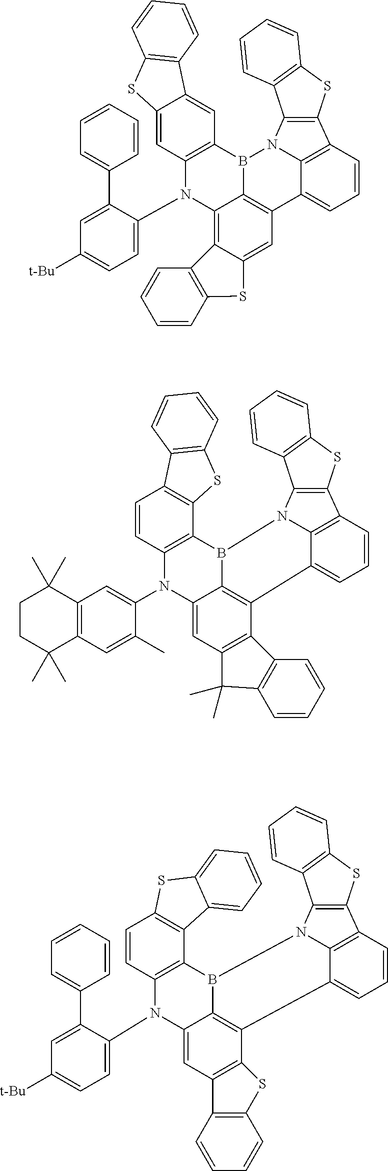 [SMILES: CC(C)(C)c1ccc(N2c3cc4sc5ccccc5c4cc3B3c4c(cc5sc6ccccc6c5c42)-c2cccc4c5sc6ccccc6c5n3c24)c(-c2ccccc2)c1 ; Cc1cc2c(cc1N1c3cc4c(c5c3B(c3c1ccc1c3sc3ccccc31)n1c3c-5cccc3c3sc5ccccc5c31)-c1ccccc1C4(C)C)C(C)(C)CCC2(C)C ; CC(C)(C)c1ccc(N2c3cc4c(sc5ccccc54)c4c3B(c3c2ccc2sc5ccccc5c32)n2c3c-4cccc3c3sc4ccccc4c32)c(-c2ccccc2)c1] 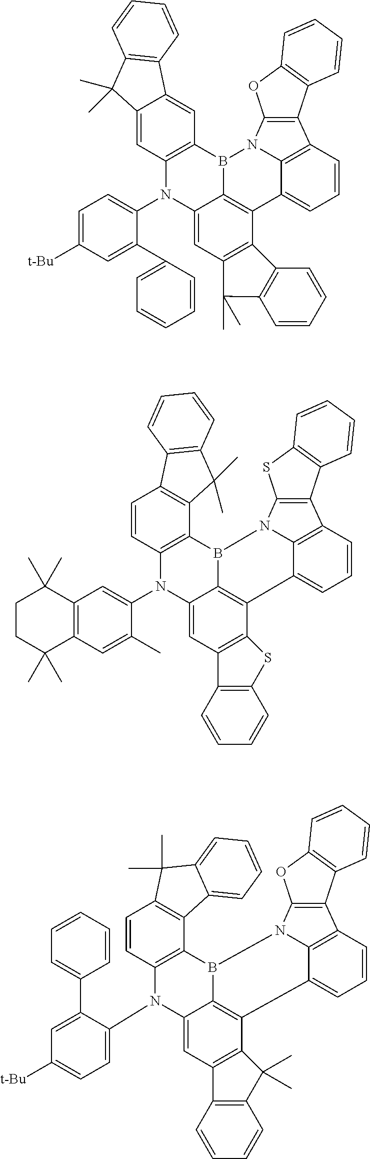 [SMILES: CC(C)(C)c1ccc(N2c3cc4c(cc3B3c5c2cc2c(c5-c5cccc6c7c8ccccc8oc7n3c56)-c3ccccc3C2(C)C)-c2ccccc2C4(C)C)c(-c2ccccc2)c1 ; Cc1cc2c(cc1N1c3ccc4c(c3B3c5c1cc1c(sc6ccccc61)c5-c1cccc5c6c7ccccc7sc6n3c15)C(C)(C)c1ccccc1-4)C(C)(C)CCC2(C)C ; CC(C)(C)c1ccc(N2c3ccc4c(c3B3c5c2cc2c(c5-c5cccc6c7c8ccccc8oc7n3c56)C(C)(C)c3ccccc3-2)-c2ccccc2C4(C)C)c(-c2ccccc2)c1] 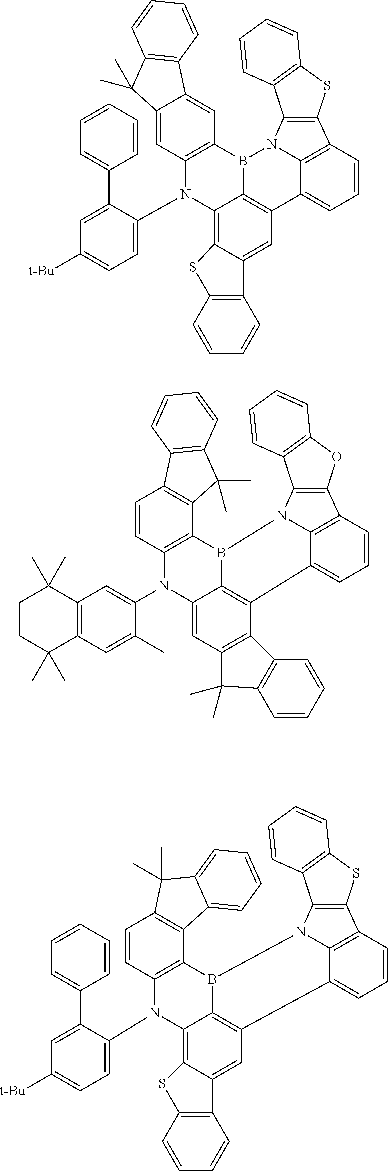 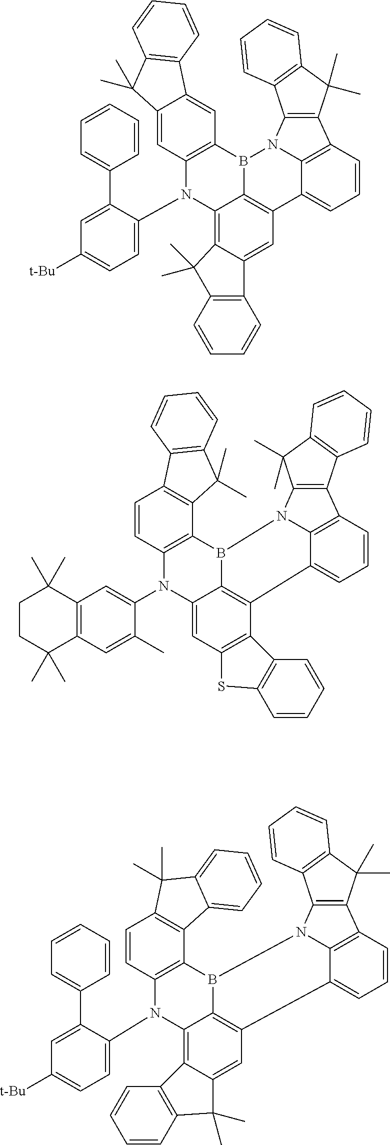 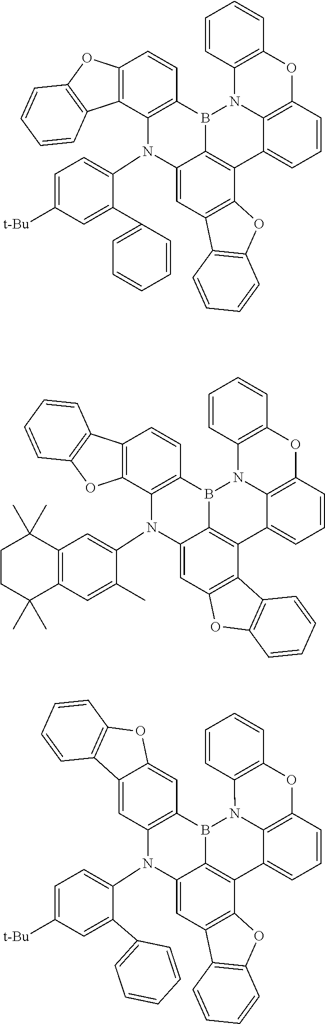 [SMILES: CC(C)(C)c1ccc(N2c3cc4c(oc5ccccc54)c4c3B(c3ccc5oc6ccccc6c5c32)N2c3ccccc3Oc3cccc-4c32)c(-c2ccccc2)c1 ; Cc1cc2c(cc1N1c3cc4oc5ccccc5c4c4c3B(c3ccc5c(oc6ccccc65)c31)N1c3ccccc3Oc3cccc-4c31)C(C)(C)CCC2(C)C ; CC(C)(C)c1ccc(N2c3cc4c(cc3B3c5c2cc2c(oc6ccccc62)c5-c2cccc5c2N3c2ccccc2O5)oc2ccccc24)c(-c2ccccc2)c1] 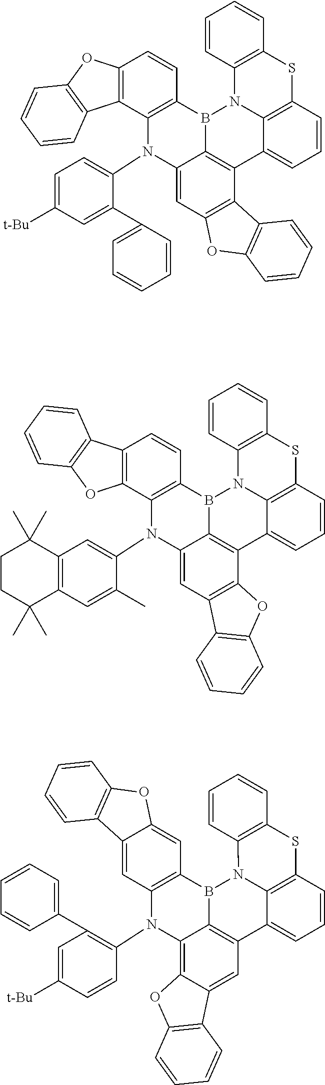 [SMILES: CC(C)(C)c1ccc(N2c3cc4oc5ccccc5c4c4c3B(c3ccc5oc6ccccc6c5c32)N2c3ccccc3Sc3cccc-4c32)c(-c2ccccc2)c1 ; Cc1cc2c(cc1N1c3cc4c(oc5ccccc54)c4c3B(c3ccc5c(oc6ccccc65)c31)N1c3ccccc3Sc3cccc-4c31)C(C)(C)CCC2(C)C ; CC(C)(C)c1ccc(N2c3cc4c(cc3B3c5c(cc6c(oc7ccccc76)c52)-c2cccc5c2N3c2ccccc2S5)oc2ccccc24)c(-c2ccccc2)c1] 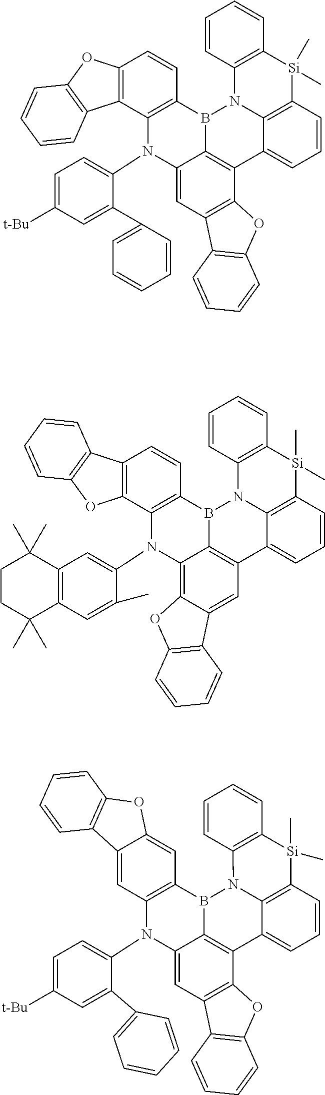 [SMILES: CC(C)(C)c1ccc(N2c3cc4c(oc5ccccc54)c4c3B(c3ccc5oc6ccccc6c5c32)N2c3ccccc3[Si](C)(C)c3cccc-4c32)c(-c2ccccc2)c1 ; Cc1cc2c(cc1N1c3c(ccc4c3oc3ccccc34)B3c4c(cc5c(oc6ccccc65)c41)-c1cccc4c1N3c1ccccc1[Si]4(C)C)C(C)(C)CCC2(C)C ; CC(C)(C)c1ccc(N2c3cc4c(cc3B3c5c2cc2c(oc6ccccc62)c5-c2cccc5c2N3c2ccccc2[Si]5(C)C)oc2ccccc24)c(-c2ccccc2)c1] 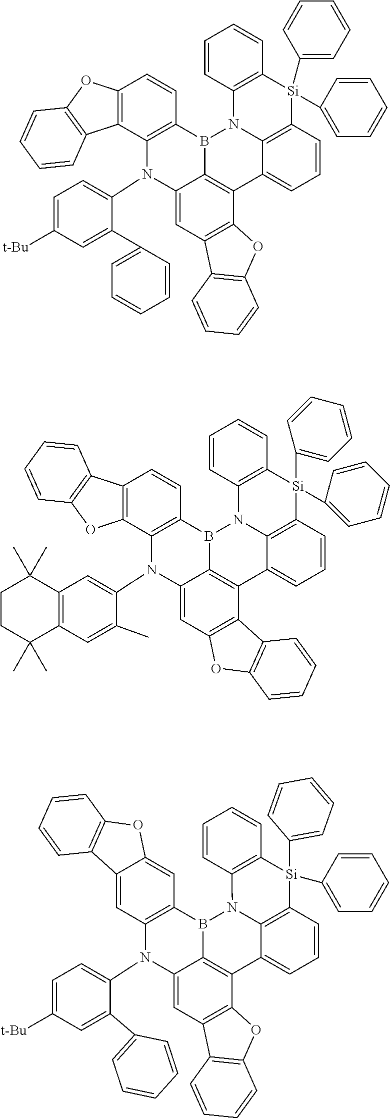 [SMILES: CC(C)(C)c1ccc(N2c3cc4c(oc5ccccc54)c4c3B(c3ccc5oc6ccccc6c5c32)N2c3ccccc3[Si](c3ccccc3)(c3ccccc3)c3cccc-4c32)c(-c2ccccc2)c1 ; Cc1cc2c(cc1N1c3cc4oc5ccccc5c4c4c3B(c3ccc5c(oc6ccccc65)c31)N1c3ccccc3[Si](c3ccccc3)(c3ccccc3)c3cccc-4c31)C(C)(C)CCC2(C)C ; CC(C)(C)c1ccc(N2c3cc4c(cc3B3c5c2cc2c(oc6ccccc62)c5-c2cccc5c2N3c2ccccc2[Si]5(c2ccccc2)c2ccccc2)oc2ccccc24)c(-c2ccccc2)c1] 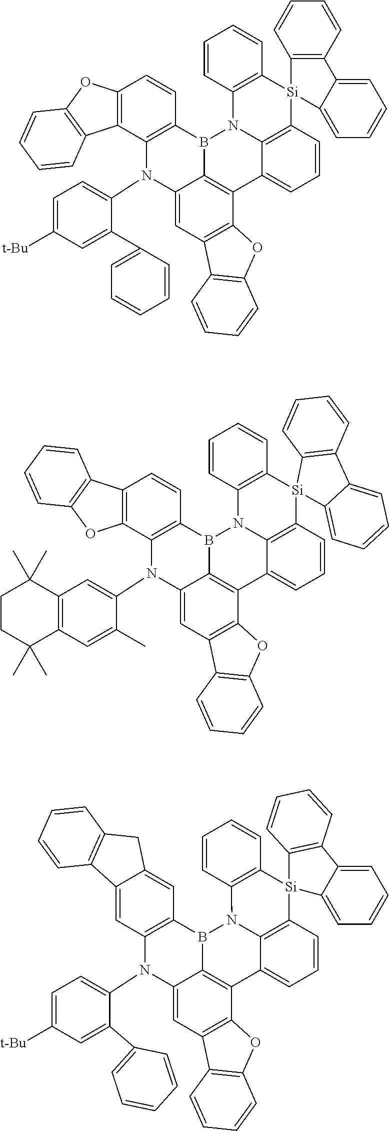 [SMILES: CC(C)(C)c1ccc(N2c3cc4c(oc5ccccc54)c4c3B(c3ccc5oc6ccccc6c5c32)N2c3ccccc3[Si]3(c5ccccc5-c5ccccc53)c3cccc-4c32)c(-c2ccccc2)c1 ; Cc1cc2c(cc1N1c3cc4c(oc5ccccc54)c4c3B(c3ccc5c(oc6ccccc65)c31)N1c3ccccc3[Si]3(c5ccccc5-c5ccccc53)c3cccc-4c31)C(C)(C)CCC2(C)C ; CC(C)(C)c1ccc(N2c3cc4c(cc3B3c5c2cc2c(oc6ccccc62)c5-c2cccc5c2N3c2ccccc2[Si]52c3ccccc3-c3ccccc32)Cc2ccccc2-4)c(-c2ccccc2)c1] 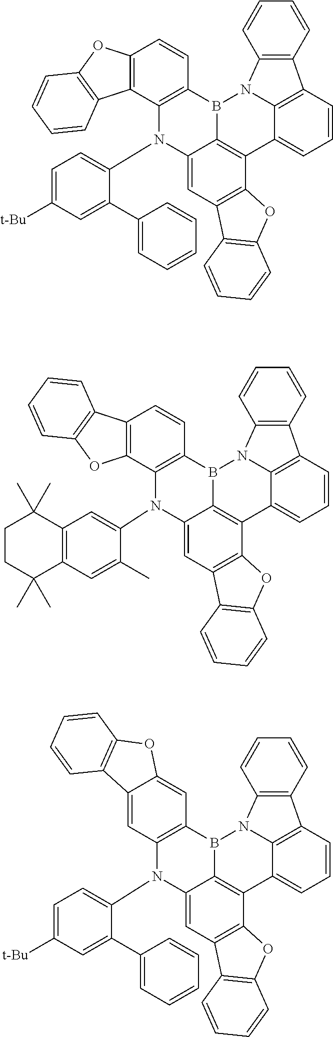 [SMILES: CC(C)(C)c1ccc(N2c3cc4c(oc5ccccc54)c4c3B(c3ccc5oc6ccccc6c5c32)n2c3ccccc3c3cccc-4c32)c(-c2ccccc2)c1 ; Cc1cc2c(cc1N1c3cc4c(oc5ccccc54)c4c3B(c3ccc5c(oc6ccccc65)c31)n1c3ccccc3c3cccc-4c31)C(C)(C)CCC2(C)C ; CC(C)(C)c1ccc(N2c3cc4c(cc3B3c5c2cc2c(oc6ccccc62)c5-c2cccc5c6ccccc6n3c25)oc2ccccc24)c(-c2ccccc2)c1] 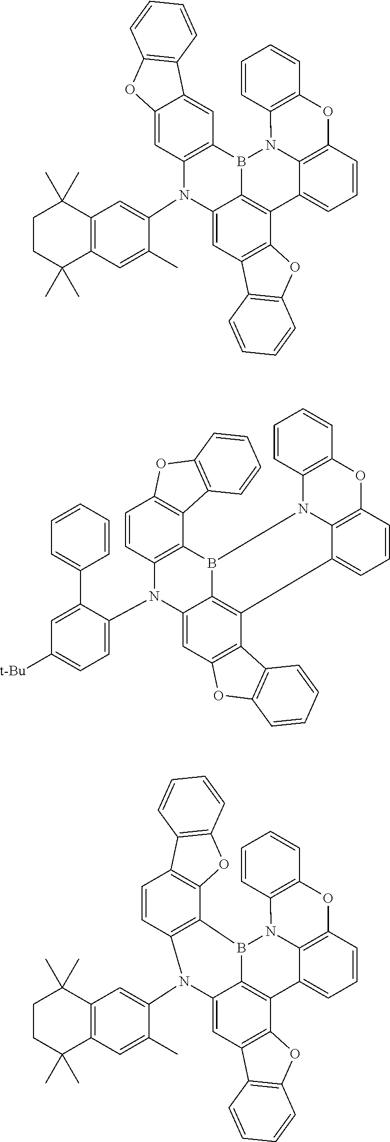 [SMILES: Cc1cc2c(cc1N1c3cc4oc5ccccc5c4cc3B3c4c1cc1c(oc5ccccc51)c4-c1cccc4c1N3c1ccccc1O4)C(C)(C)CCC2(C)C ; CC(C)(C)c1ccc(N2c3cc4oc5ccccc5c4c4c3B(c3c2ccc2oc5ccccc5c32)N2c3ccccc3Oc3cccc-4c32)c(-c2ccccc2)c1 ; Cc1cc2c(cc1N1c3cc4c(oc5ccccc54)c4c3B(c3c1ccc1c3oc3ccccc31)N1c3ccccc3Oc3cccc-4c31)C(C)(C)CCC2(C)C] 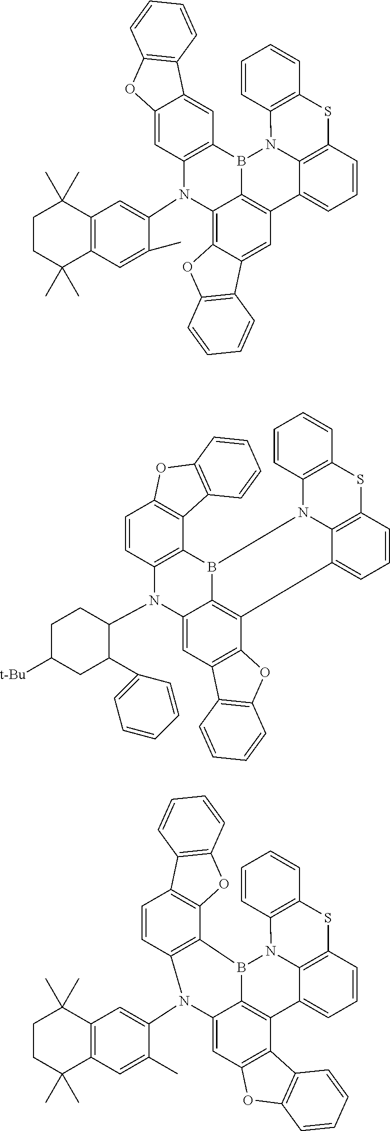 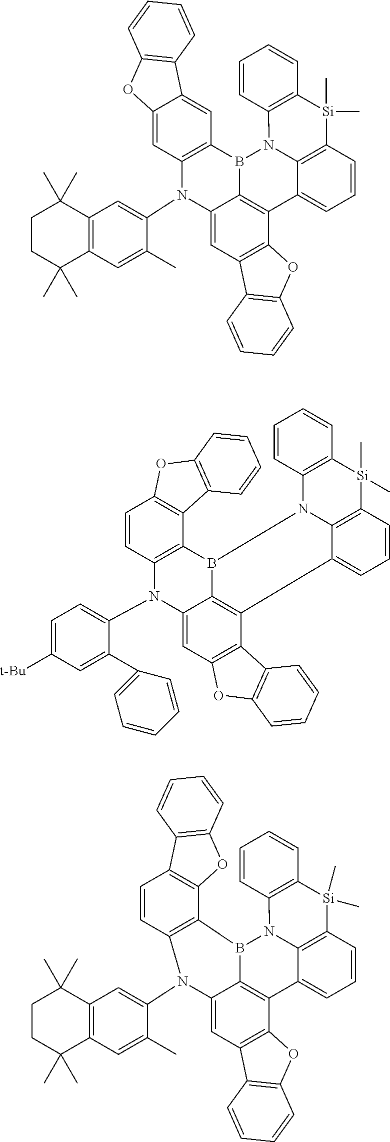 [SMILES: Cc1cc2c(cc1N1c3cc4oc5ccccc5c4cc3B3c4c1cc1c(oc5ccccc51)c4-c1cccc4c1N3c1ccccc1[Si]4(C)C)C(C)(C)CCC2(C)C ; CC(C)(C)c1ccc(N2c3cc4oc5ccccc5c4c4c3B(c3c2ccc2oc5ccccc5c32)N2c3ccccc3[Si](C)(C)c3cccc-4c32)c(-c2ccccc2)c1 ; Cc1cc2c(cc1N1c3cc4c(oc5ccccc54)c4c3B(c3c1ccc1c3oc3ccccc31)N1c3ccccc3[Si](C)(C)c3cccc-4c31)C(C)(C)CCC2(C)C] 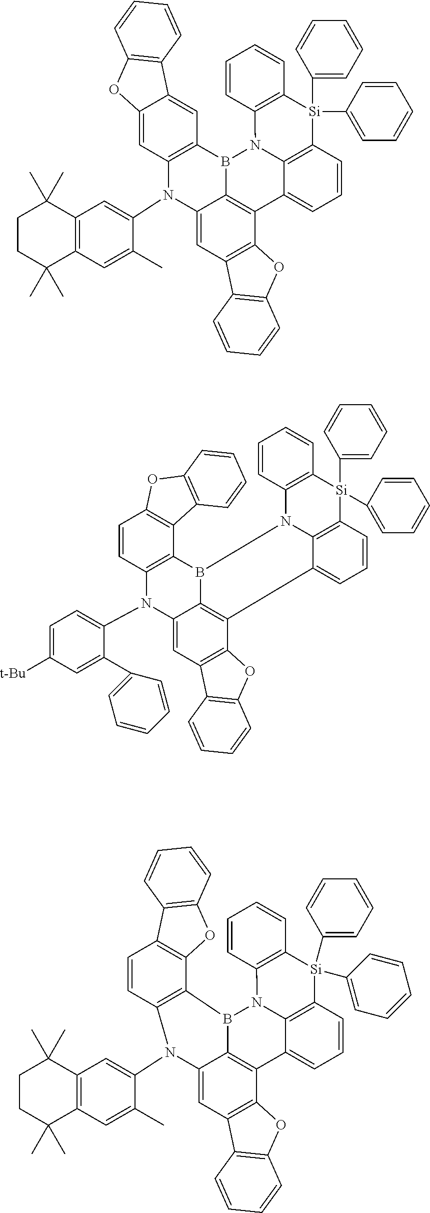 [SMILES: Cc1cc2c(cc1N1c3cc4oc5ccccc5c4cc3B3c4c1cc1c(oc5ccccc51)c4-c1cccc4c1N3c1ccccc1[Si]4(c1ccccc1)c1ccccc1)C(C)(C)CCC2(C)C ; CC(C)(C)c1ccc(N2c3cc4c(oc5ccccc54)c4c3B(c3c2ccc2oc5ccccc5c32)N2c3ccccc3[Si](c3ccccc3)(c3ccccc3)c3cccc-4c32)c(-c2ccccc2)c1 ; Cc1cc2c(cc1N1c3cc4c(oc5ccccc54)c4c3B(c3c1ccc1c3oc3ccccc31)N1c3ccccc3[Si](c3ccccc3)(c3ccccc3)c3cccc-4c31)C(C)(C)CCC2(C)C] 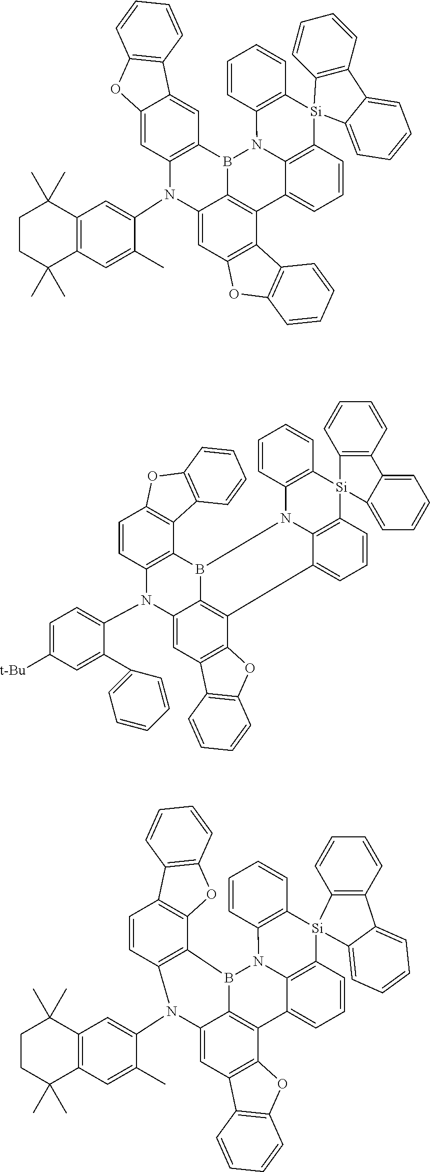 [SMILES: Cc1cc2c(cc1N1c3cc4oc5ccccc5c4cc3B3c4c1cc1oc5ccccc5c1c4-c1cccc4c1N3c1ccccc1[Si]41c3ccccc3-c3ccccc31)C(C)(C)CCC2(C)C ; CC(C)(C)c1ccc(N2c3cc4c(oc5ccccc54)c4c3B(c3c2ccc2oc5ccccc5c32)N2c3ccccc3[Si]3(c5ccccc5-c5ccccc53)c3cccc-4c32)c(-c2ccccc2)c1 ; Cc1cc2c(cc1N1c3cc4c(oc5ccccc54)c4c3B(c3c1ccc1c3oc3ccccc31)N1c3ccccc3[Si]3(c5ccccc5-c5ccccc53)c3cccc-4c31)C(C)(C)CCC2(C)C] 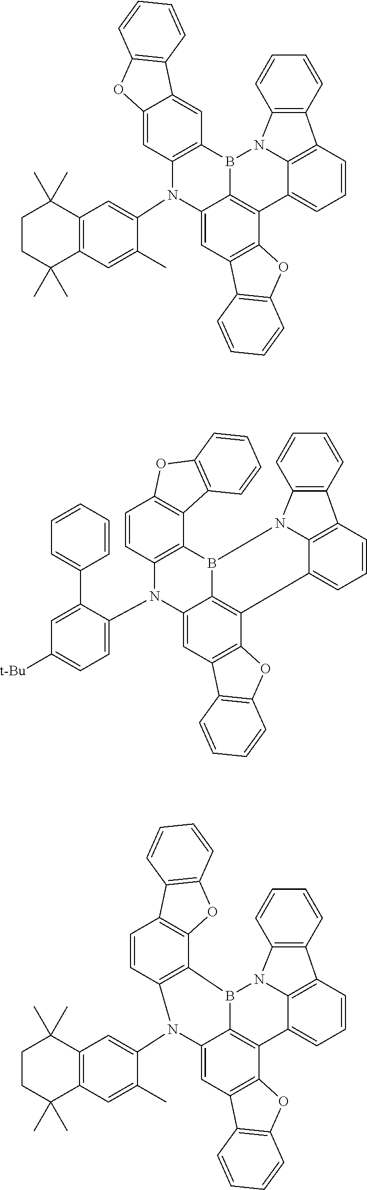 [SMILES: Cc1cc2c(cc1N1c3cc4oc5ccccc5c4cc3B3c4c1cc1c(oc5ccccc51)c4-c1cccc4c5ccccc5n3c14)C(C)(C)CCC2(C)C ; CC(C)(C)c1ccc(N2c3cc4c(oc5ccccc54)c4c3B(c3c2ccc2oc5ccccc5c32)n2c3ccccc3c3cccc-4c32)c(-c2ccccc2)c1 ; Cc1cc2c(cc1N1c3cc4c(oc5ccccc54)c4c3B(c3c1ccc1c3oc3ccccc31)n1c3ccccc3c3cccc-4c31)C(C)(C)CCC2(C)C] 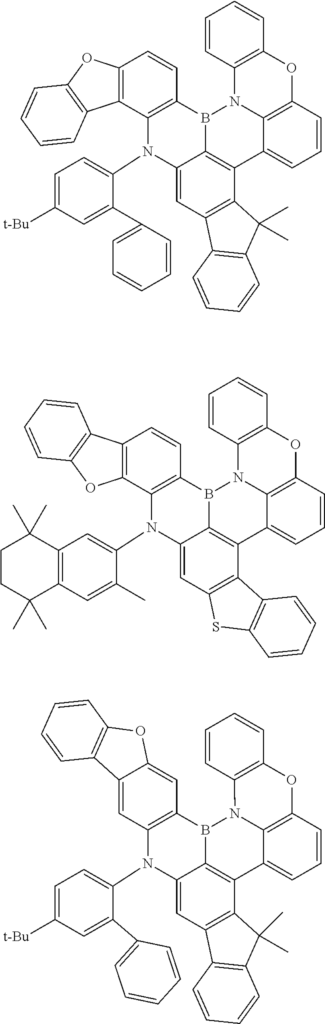 [SMILES: CC(C)(C)c1ccc(N2c3cc4c(c5c3B(c3ccc6oc7ccccc7c6c32)N2c3ccccc3Oc3cccc-5c32)C(C)(C)c2ccccc2-4)c(-c2ccccc2)c1 ; Cc1cc2c(cc1N1c3cc4sc5ccccc5c4c4c3B(c3ccc5c(oc6ccccc65)c31)N1c3ccccc3Oc3cccc-4c31)C(C)(C)CCC2(C)C ; CC(C)(C)c1ccc(N2c3cc4c(cc3B3c5c2cc2c(c5-c5cccc6c5N3c3ccccc3O6)C(C)(C)c3ccccc3-2)oc2ccccc24)c(-c2ccccc2)c1] 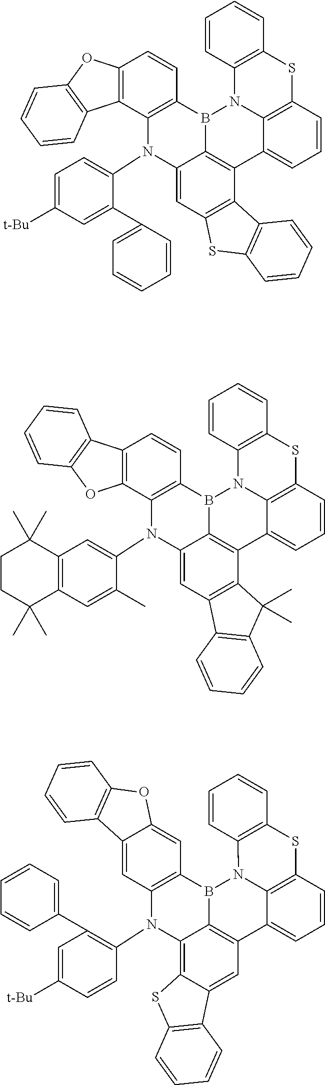 [SMILES: CC(C)(C)c1ccc(N2c3cc4sc5ccccc5c4c4c3B(c3ccc5oc6ccccc6c5c32)N2c3ccccc3Sc3cccc-4c32)c(-c2ccccc2)c1 ; Cc1cc2c(cc1N1c3cc4c(c5c3B(c3ccc6c(oc7ccccc76)c31)N1c3ccccc3Sc3cccc-5c31)C(C)(C)c1ccccc1-4)C(C)(C)CCC2(C)C ; CC(C)(C)c1ccc(N2c3cc4c(cc3B3c5c(cc6c(sc7ccccc76)c52)-c2cccc5c2N3c2ccccc2S5)oc2ccccc24)c(-c2ccccc2)c1] 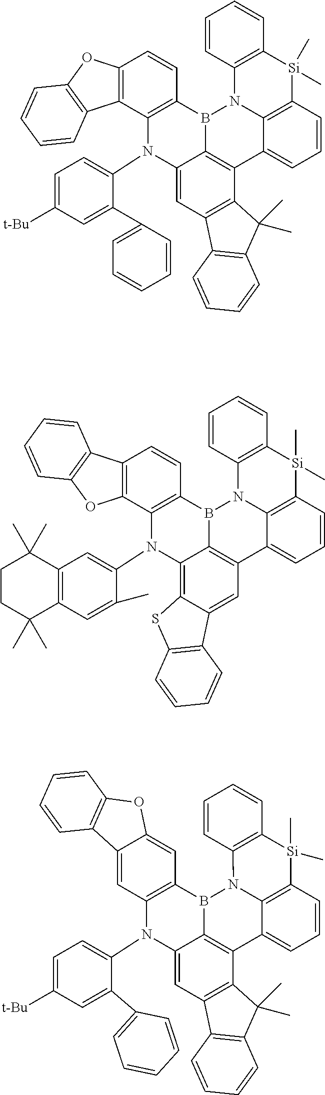 [SMILES: CC(C)(C)c1ccc(N2c3cc4c(c5c3B(c3ccc6oc7ccccc7c6c32)N2c3ccccc3[Si](C)(C)c3cccc-5c32)C(C)(C)c2ccccc2-4)c(-c2ccccc2)c1 ; Cc1cc2c(cc1N1c3c(ccc4c3oc3ccccc34)B3c4c(cc5c(sc6ccccc65)c41)-c1cccc4c1N3c1ccccc1[Si]4(C)C)C(C)(C)CCC2(C)C ; CC(C)(C)c1ccc(N2c3cc4c(cc3B3c5c2cc2c(c5-c5cccc6c5N3c3ccccc3[Si]6(C)C)C(C)(C)c3ccccc3-2)oc2ccccc24)c(-c2ccccc2)c1] 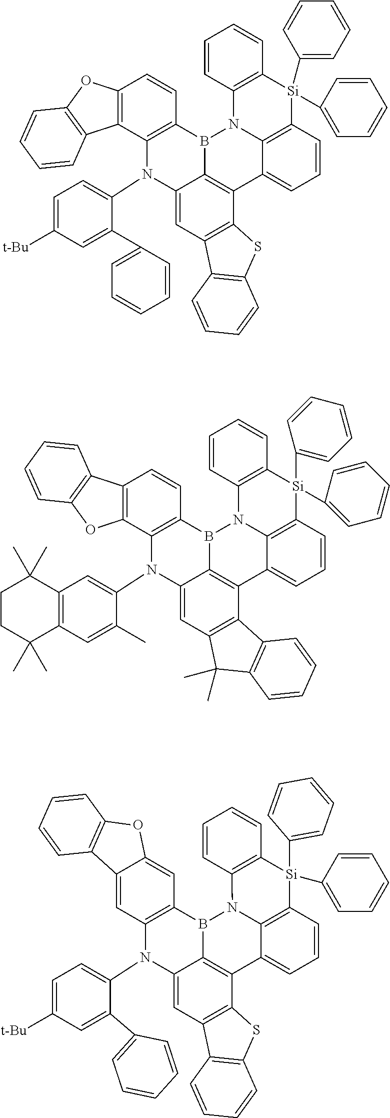 [SMILES: CC(C)(C)c1ccc(N2c3cc4c(sc5ccccc54)c4c3B(c3ccc5oc6ccccc6c5c32)N2c3ccccc3[Si](c3ccccc3)(c3ccccc3)c3cccc-4c32)c(-c2ccccc2)c1 ; Cc1cc2c(cc1N1c3cc4c(c5c3B(c3ccc6c(oc7ccccc76)c31)N1c3ccccc3[Si](c3ccccc3)(c3ccccc3)c3cccc-5c31)-c1ccccc1C4(C)C)C(C)(C)CCC2(C)C ; CC(C)(C)c1ccc(N2c3cc4c(cc3B3c5c2cc2c(sc6ccccc62)c5-c2cccc5c2N3c2ccccc2[Si]5(c2ccccc2)c2ccccc2)oc2ccccc24)c(-c2ccccc2)c1] 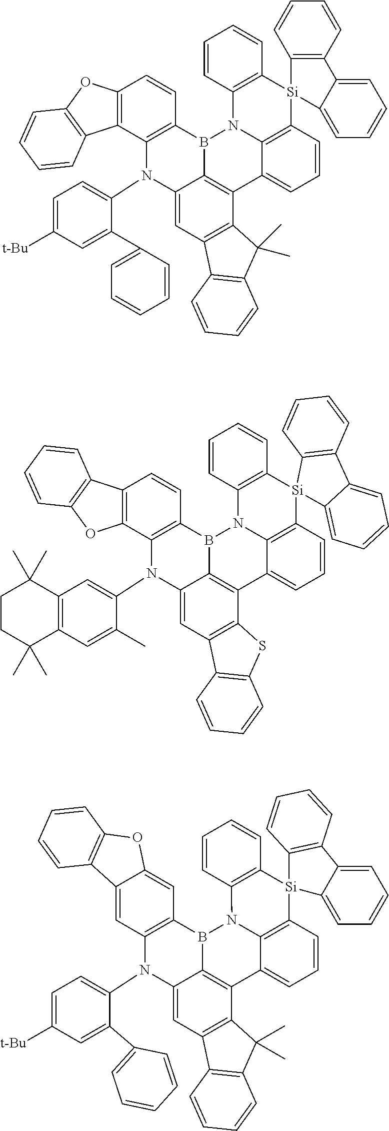 [SMILES: CC(C)(C)c1ccc(N2c3cc4c(c5c3B(c3ccc6oc7ccccc7c6c32)N2c3ccccc3[Si]3(c6ccccc6-c6ccccc63)c3cccc-5c32)C(C)(C)c2ccccc2-4)c(-c2ccccc2)c1 ; Cc1cc2c(cc1N1c3cc4c(sc5ccccc54)c4c3B(c3ccc5c(oc6ccccc65)c31)N1c3ccccc3[Si]3(c5ccccc5-c5ccccc53)c3cccc-4c31)C(C)(C)CCC2(C)C ; CC(C)(C)c1ccc(N2c3cc4c(cc3B3c5c2cc2c(c5-c5cccc6c5N3c3ccccc3[Si]63c5ccccc5-c5ccccc53)C(C)(C)c3ccccc3-2)oc2ccccc24)c(-c2ccccc2)c1] 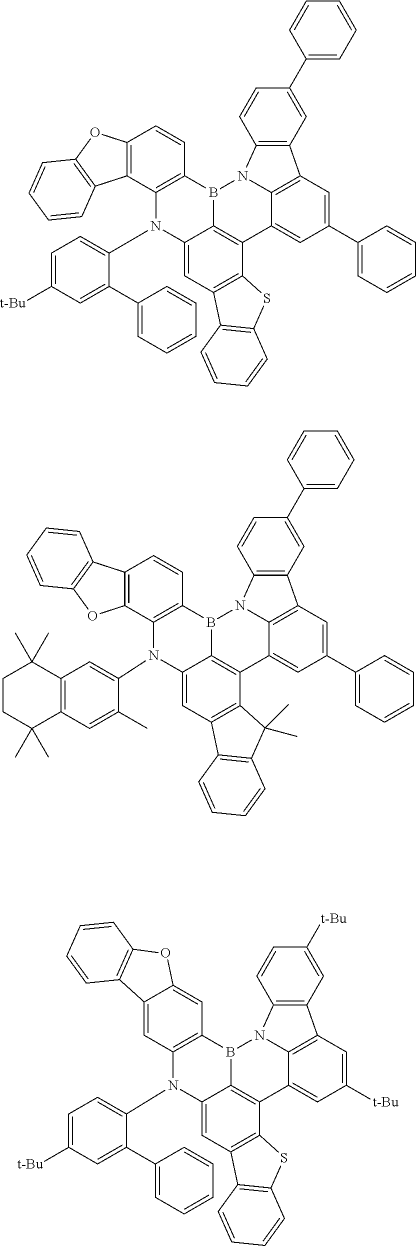 [SMILES: CC(C)(C)c1ccc(N2c3cc4c(sc5ccccc54)c4c3B(c3ccc5oc6ccccc6c5c32)n2c3ccc(-c5ccccc5)cc3c3cc(-c5ccccc5)cc-4c32)c(-c2ccccc2)c1 ; Cc1cc2c(cc1N1c3cc4c(c5c3B(c3ccc6c(oc7ccccc76)c31)n1c3ccc(-c6ccccc6)cc3c3cc(-c6ccccc6)cc-5c31)C(C)(C)c1ccccc1-4)C(C)(C)CCC2(C)C ; CC(C)(C)c1ccc(N2c3cc4c(cc3B3c5c2cc2c(sc6ccccc62)c5-c2cc(C(C)(C)C)cc5c6cc(C(C)(C)C)ccc6n3c25)oc2ccccc24)c(-c2ccccc2)c1] 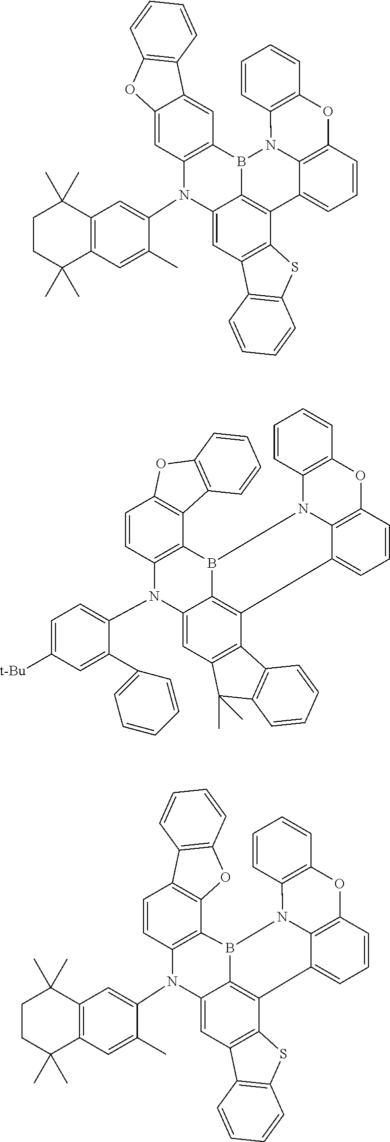 [SMILES: Cc1cc2c(cc1N1c3cc4oc5ccccc5c4cc3B3c4c1cc1c(sc5ccccc51)c4-c1cccc4c1N3c1ccccc1O4)C(C)(C)CCC2(C)C ; CC(C)(C)c1ccc(N2c3cc4c(c5c3B(c3c2ccc2oc6ccccc6c32)N2c3ccccc3Oc3cccc-5c32)-c2ccccc2C4(C)C)c(-c2ccccc2)c1 ; Cc1cc2c(cc1N1c3cc4c(sc5ccccc54)c4c3B(c3c1ccc1c3oc3ccccc31)N1c3ccccc3Oc3cccc-4c31)C(C)(C)CCC2(C)C] 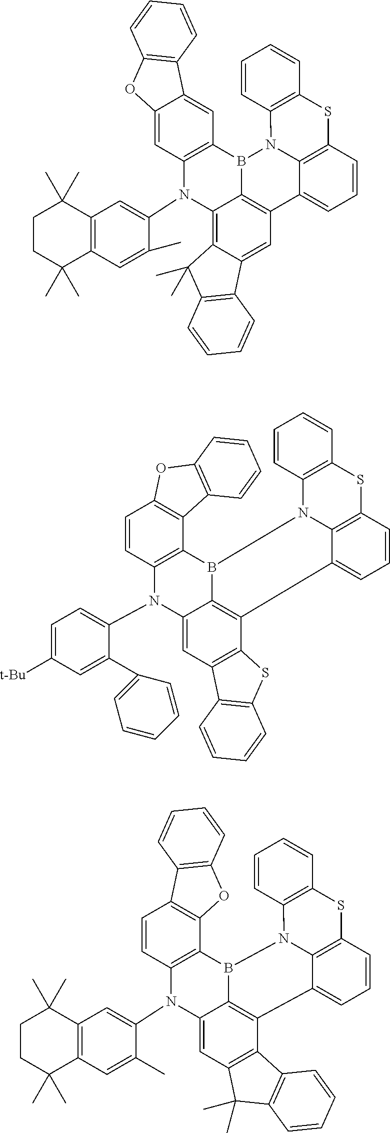 [SMILES: Cc1cc2c(cc1N1c3cc4oc5ccccc5c4cc3B3c4c(cc5c(c41)C(C)(C)c1ccccc1-5)-c1cccc4c1N3c1ccccc1S4)C(C)(C)CCC2(C)C ; CC(C)(C)c1ccc(N2c3cc4c(sc5ccccc54)c4c3B(c3c2ccc2oc5ccccc5c32)N2c3ccccc3Sc3cccc-4c32)c(-c2ccccc2)c1 ; Cc1cc2c(cc1N1c3cc4c(c5c3B(c3c1ccc1c3oc3ccccc31)N1c3ccccc3Sc3cccc-5c31)-c1ccccc1C4(C)C)C(C)(C)CCC2(C)C] 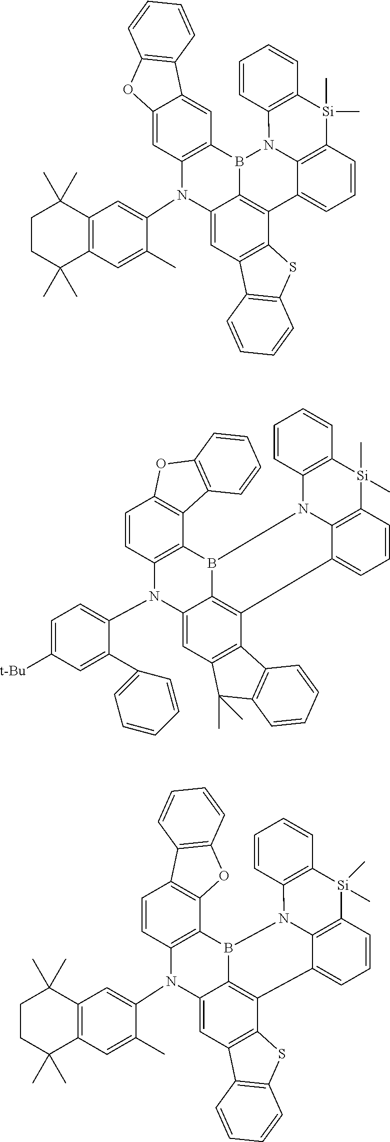 [SMILES: Cc1cc2c(cc1N1c3cc4oc5ccccc5c4cc3B3c4c1cc1c(sc5ccccc51)c4-c1cccc4c1N3c1ccccc1[Si]4(C)C)C(C)(C)CCC2(C)C ; CC(C)(C)c1ccc(N2c3cc4c(c5c3B(c3c2ccc2oc6ccccc6c32)N2c3ccccc3[Si](C)(C)c3cccc-5c32)-c2ccccc2C4(C)C)c(-c2ccccc2)c1 ; Cc1cc2c(cc1N1c3cc4c(sc5ccccc54)c4c3B(c3c1ccc1c3oc3ccccc31)N1c3ccccc3[Si](C)(C)c3cccc-4c31)C(C)(C)CCC2(C)C] 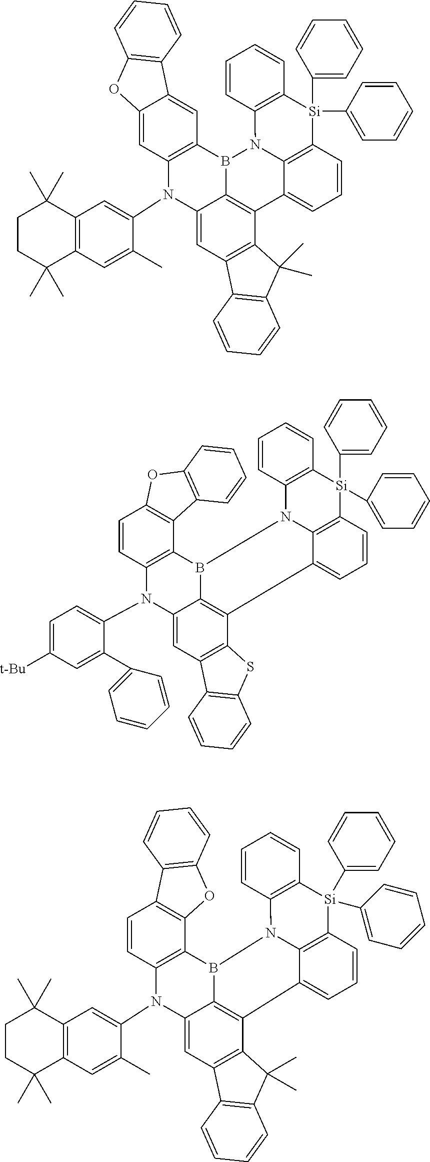 [SMILES: Cc1cc2c(cc1N1c3cc4oc5ccccc5c4cc3B3c4c1cc1c(c4-c4cccc5c4N3c3ccccc3[Si]5(c3ccccc3)c3ccccc3)C(C)(C)c3ccccc3-1)C(C)(C)CCC2(C)C ; CC(C)(C)c1ccc(N2c3cc4c(sc5ccccc54)c4c3B(c3c2ccc2oc5ccccc5c32)N2c3ccccc3[Si](c3ccccc3)(c3ccccc3)c3cccc-4c32)c(-c2ccccc2)c1 ; Cc1cc2c(cc1N1c3cc4c(c5c3B(c3c1ccc1c3oc3ccccc31)N1c3ccccc3[Si](c3ccccc3)(c3ccccc3)c3cccc-5c31)C(C)(C)c1ccccc1-4)C(C)(C)CCC2(C)C] 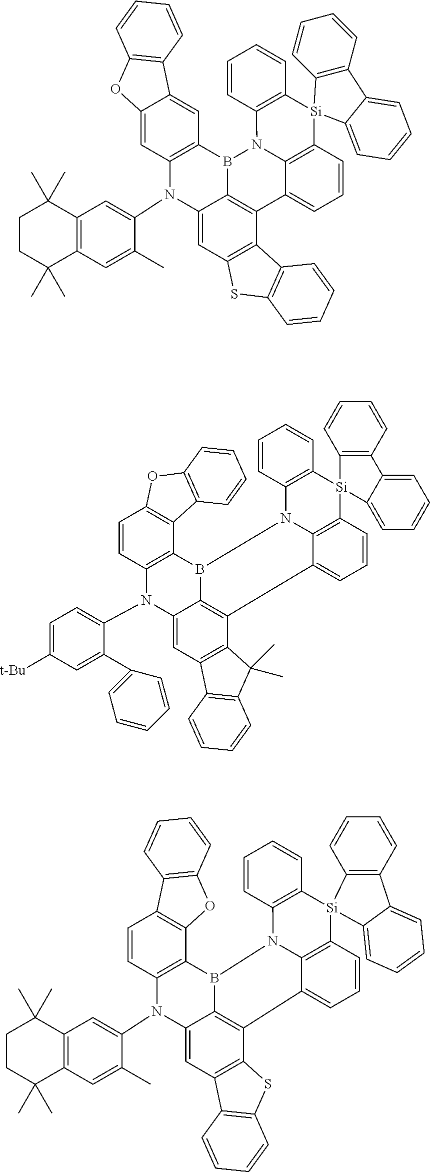 [SMILES: Cc1cc2c(cc1N1c3cc4oc5ccccc5c4cc3B3c4c1cc1sc5ccccc5c1c4-c1cccc4c1N3c1ccccc1[Si]41c3ccccc3-c3ccccc31)C(C)(C)CCC2(C)C ; CC(C)(C)c1ccc(N2c3cc4c(c5c3B(c3c2ccc2oc6ccccc6c32)N2c3ccccc3[Si]3(c6ccccc6-c6ccccc63)c3cccc-5c32)C(C)(C)c2ccccc2-4)c(-c2ccccc2)c1 ; Cc1cc2c(cc1N1c3cc4c(sc5ccccc54)c4c3B(c3c1ccc1c3oc3ccccc31)N1c3ccccc3[Si]3(c5ccccc5-c5ccccc53)c3cccc-4c31)C(C)(C)CCC2(C)C] 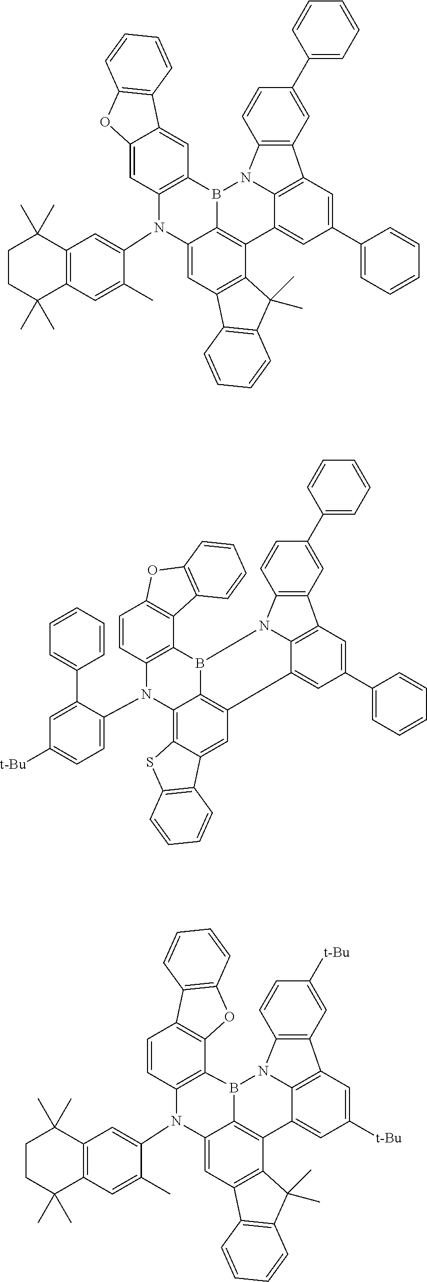 [SMILES: Cc1cc2c(cc1N1c3cc4oc5ccccc5c4cc3B3c4c1cc1c(c4-c4cc(-c5ccccc5)cc5c6cc(-c7ccccc7)ccc6n3c45)C(C)(C)c3ccccc3-1)C(C)(C)CCC2(C)C ; CC(C)(C)c1ccc(N2c3ccc4oc5ccccc5c4c3B3c4c(cc5c(sc6ccccc65)c42)-c2cc(-c4ccccc4)cc4c5cc(-c6ccccc6)ccc5n3c24)c(-c2ccccc2)c1 ; Cc1cc2c(cc1N1c3cc4c(c5c3B(c3c1ccc1c3oc3ccccc31)n1c3ccc(C(C)(C)C)cc3c3cc(C(C)(C)C)cc-5c31)C(C)(C)c1ccccc1-4)C(C)(C)CCC2(C)C] 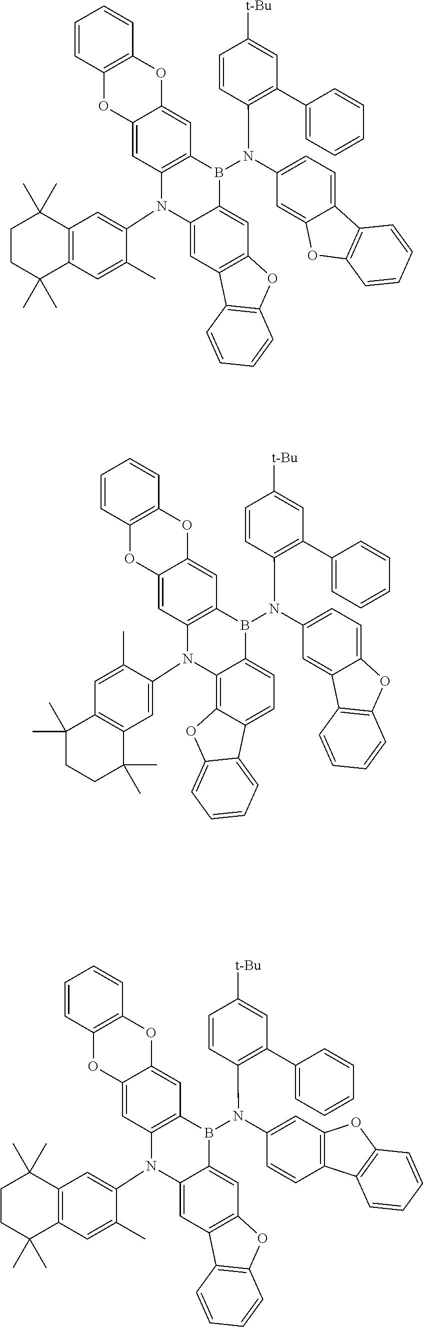 [SMILES: Cc1cc2c(cc1N1c3cc4c(cc3B(N(c3ccc5c(c3)oc3ccccc35)c3ccc(C(C)(C)C)cc3-c3ccccc3)c3cc5oc6ccccc6c5cc31)Oc1ccccc1O4)C(C)(C)CCC2(C)C ; Cc1cc2c(cc1N1c3cc4c(cc3B(N(c3ccc5oc6ccccc6c5c3)c3ccc(C(C)(C)C)cc3-c3ccccc3)c3ccc5c(oc6ccccc65)c31)Oc1ccccc1O4)C(C)(C)CCC2(C)C ; Cc1cc2c(cc1N1c3cc4c(cc3B(N(c3ccc5c(c3)oc3ccccc35)c3ccc(C(C)(C)C)cc3-c3ccccc3)c3cc5oc6ccccc6c5cc31)Oc1ccccc1O4)C(C)(C)CCC2(C)C] 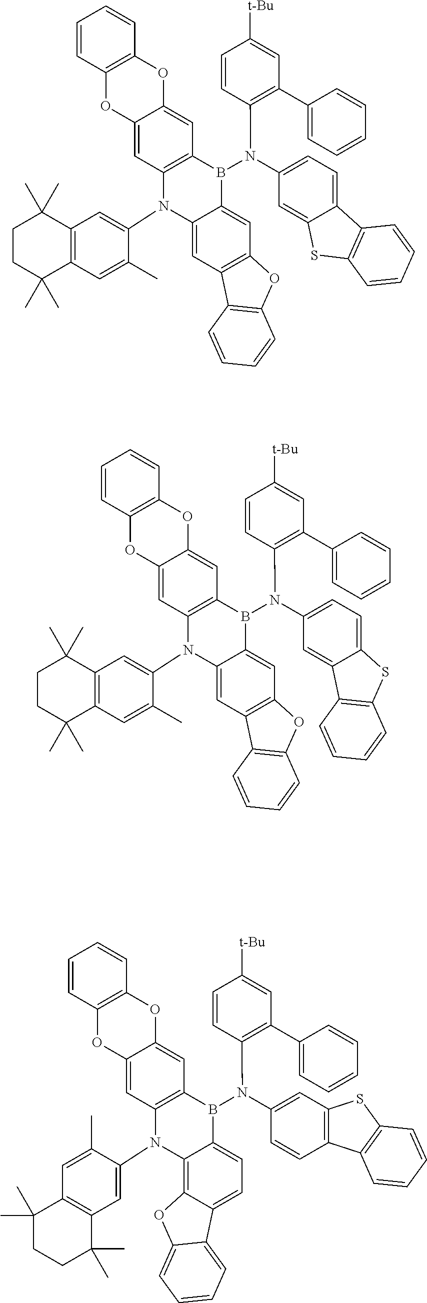 [SMILES: Cc1cc2c(cc1N1c3cc4c(cc3B(N(c3ccc5c(c3)sc3ccccc35)c3ccc(C(C)(C)C)cc3-c3ccccc3)c3cc5oc6ccccc6c5cc31)Oc1ccccc1O4)C(C)(C)CCC2(C)C ; Cc1cc2c(cc1N1c3cc4c(cc3B(N(c3ccc5sc6ccccc6c5c3)c3ccc(C(C)(C)C)cc3-c3ccccc3)c3cc5oc6ccccc6c5cc31)Oc1ccccc1O4)C(C)(C)CCC2(C)C ; Cc1cc2c(cc1N1c3cc4c(cc3B(N(c3ccc5c(c3)sc3ccccc35)c3ccc(C(C)(C)C)cc3-c3ccccc3)c3ccc5c(oc6ccccc65)c31)Oc1ccccc1O4)C(C)(C)CCC2(C)C] 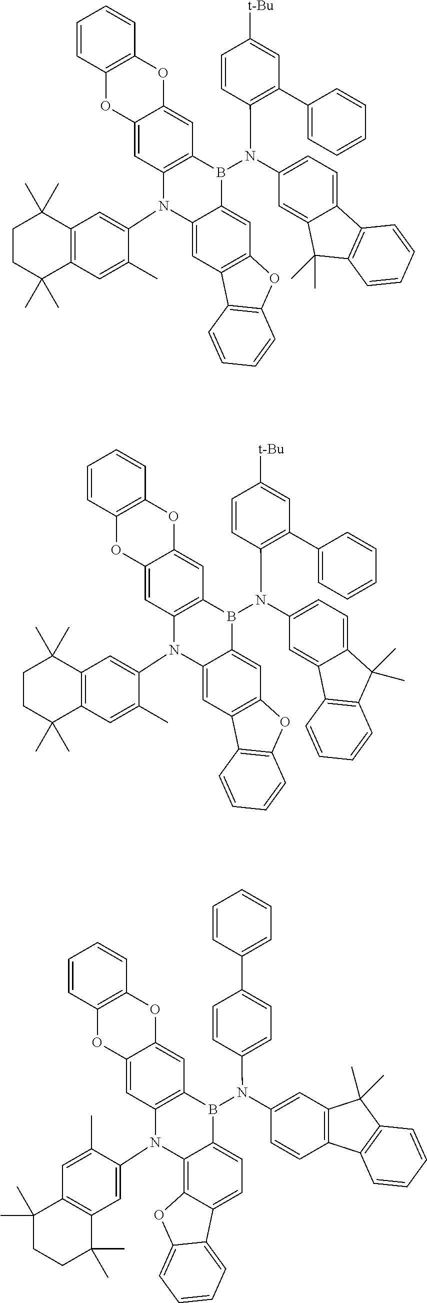 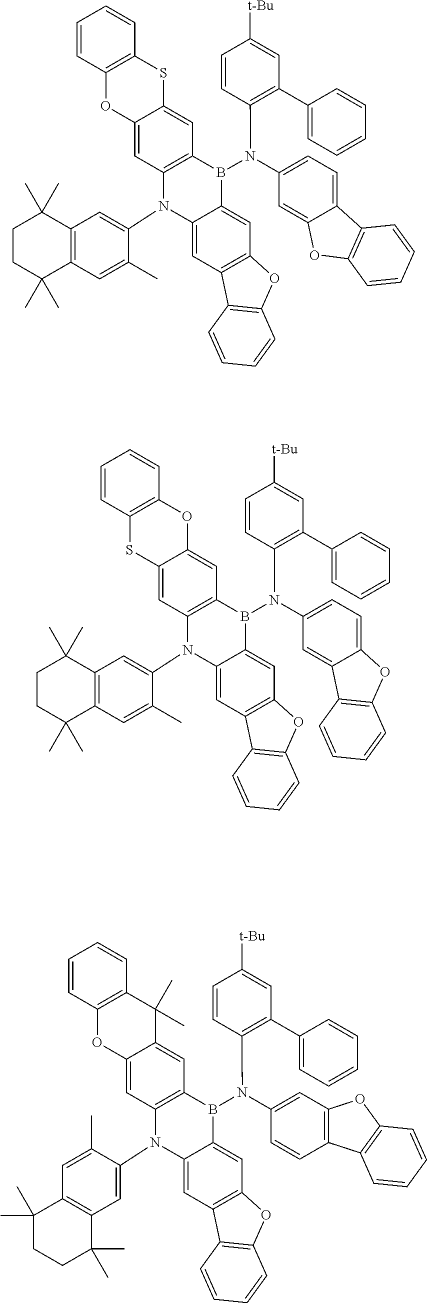 [SMILES: Cc1cc2c(cc1N1c3cc4c(cc3B(N(c3ccc5c(c3)oc3ccccc35)c3ccc(C(C)(C)C)cc3-c3ccccc3)c3cc5oc6ccccc6c5cc31)Sc1ccccc1O4)C(C)(C)CCC2(C)C ; Cc1cc2c(cc1N1c3cc4c(cc3B(N(c3ccc5oc6ccccc6c5c3)c3ccc(C(C)(C)C)cc3-c3ccccc3)c3cc5oc6ccccc6c5cc31)Oc1ccccc1S4)C(C)(C)CCC2(C)C ; Cc1cc2c(cc1N1c3cc4c(cc3B(N(c3ccc5c(c3)oc3ccccc35)c3ccc(C(C)(C)C)cc3-c3ccccc3)c3cc5oc6ccccc6c5cc31)C(C)(C)c1ccccc1O4)C(C)(C)CCC2(C)C] 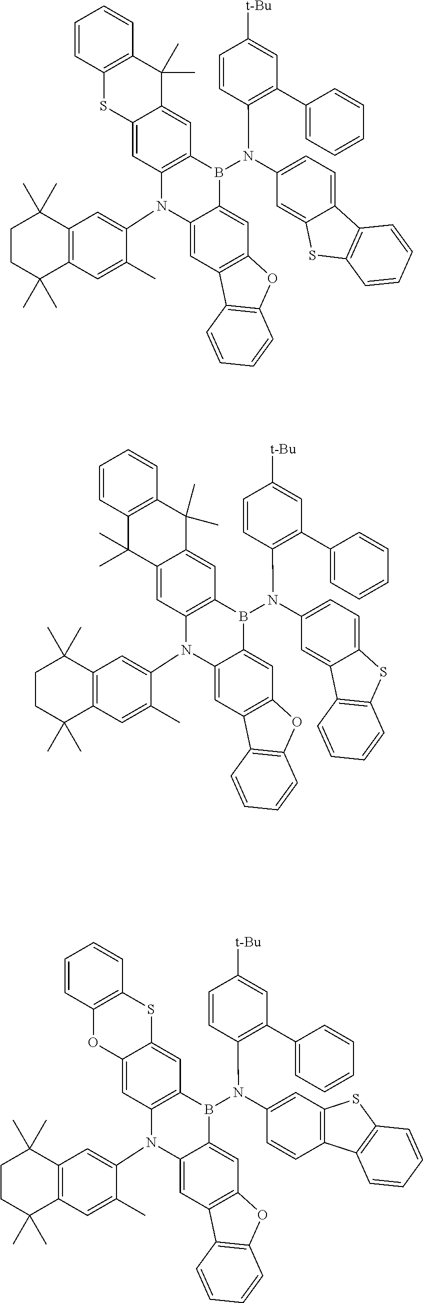 [SMILES: Cc1cc2c(cc1N1c3cc4c(cc3B(N(c3ccc5c(c3)sc3ccccc35)c3ccc(C(C)(C)C)cc3-c3ccccc3)c3cc5oc6ccccc6c5cc31)C(C)(C)c1ccccc1S4)C(C)(C)CCC2(C)C ; Cc1cc2c(cc1N1c3cc4c(cc3B(N(c3ccc5sc6ccccc6c5c3)c3ccc(C(C)(C)C)cc3-c3ccccc3)c3cc5oc6ccccc6c5cc31)C(C)(C)c1ccccc1C4(C)C)C(C)(C)CCC2(C)C ; Cc1cc2c(cc1N1c3cc4c(cc3B(N(c3ccc5c(c3)sc3ccccc35)c3ccc(C(C)(C)C)cc3-c3ccccc3)c3cc5oc6ccccc6c5cc31)Sc1ccccc1O4)C(C)(C)CCC2(C)C] 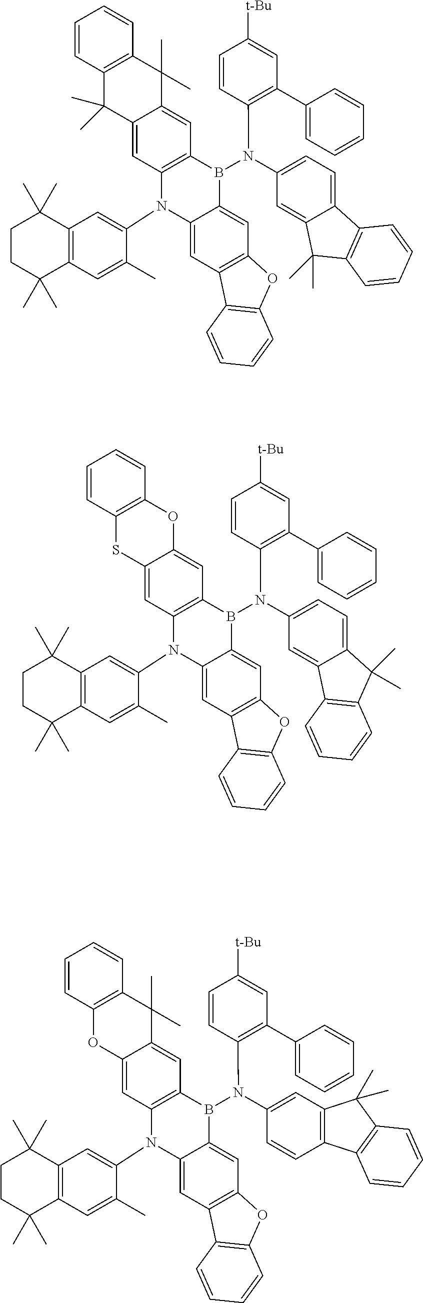 [SMILES: Cc1cc2c(cc1N1c3cc4c(cc3B(N(c3ccc5c(c3)C(C)(C)c3ccccc3-5)c3ccc(C(C)(C)C)cc3-c3ccccc3)c3cc5oc6ccccc6c5cc31)C(C)(C)c1ccccc1C4(C)C)C(C)(C)CCC2(C)C ; Cc1cc2c(cc1N1c3cc4c(cc3B(N(c3ccc5c(c3)-c3ccccc3C5(C)C)c3ccc(C(C)(C)C)cc3-c3ccccc3)c3cc5oc6ccccc6c5cc31)Oc1ccccc1S4)C(C)(C)CCC2(C)C ; Cc1cc2c(cc1N1c3cc4c(cc3B(N(c3ccc5c(c3)C(C)(C)c3ccccc3-5)c3ccc(C(C)(C)C)cc3-c3ccccc3)c3cc5oc6ccccc6c5cc31)C(C)(C)c1ccccc1O4)C(C)(C)CCC2(C)C] 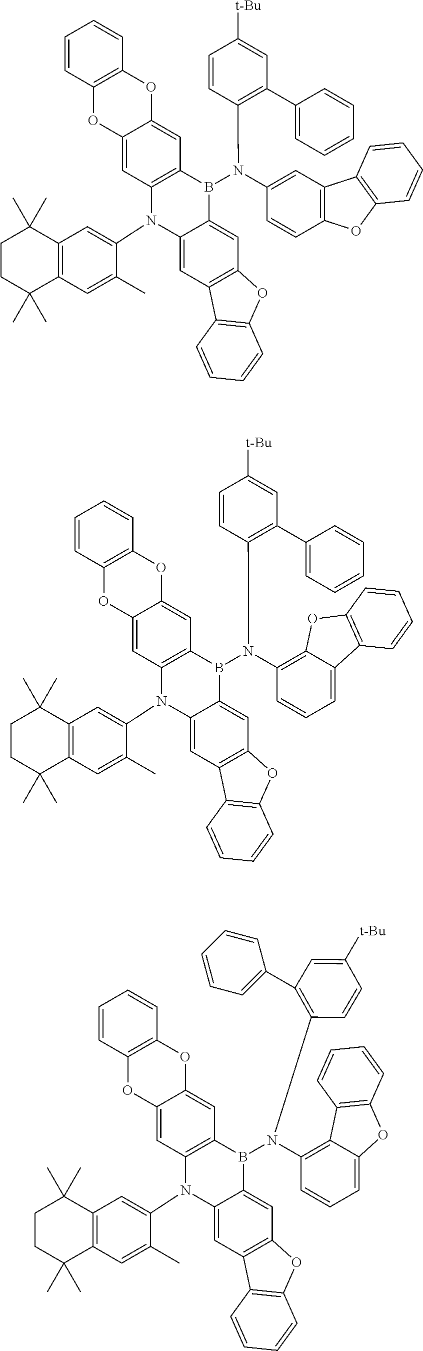 [SMILES: Cc1cc2c(cc1N1c3cc4c(cc3B(N(c3ccc5oc6ccccc6c5c3)c3ccc(C(C)(C)C)cc3-c3ccccc3)c3cc5oc6ccccc6c5cc31)Oc1ccccc1O4)C(C)(C)CCC2(C)C ; Cc1cc2c(cc1N1c3cc4c(cc3B(N(c3ccc(C(C)(C)C)cc3-c3ccccc3)c3cccc5c3oc3ccccc35)c3cc5oc6ccccc6c5cc31)Oc1ccccc1O4)C(C)(C)CCC2(C)C ; Cc1cc2c(cc1N1c3cc4c(cc3B(N(c3ccc(C(C)(C)C)cc3-c3ccccc3)c3cccc5oc6ccccc6c35)c3cc5oc6ccccc6c5cc31)Oc1ccccc1O4)C(C)(C)CCC2(C)C] 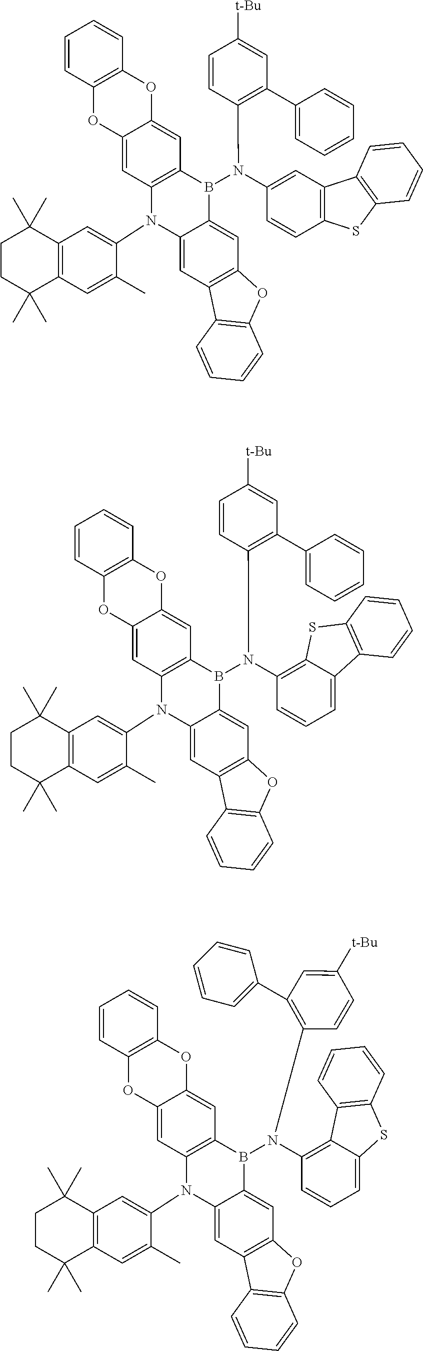 [SMILES: Cc1cc2c(cc1N1c3cc4c(cc3B(N(c3ccc5sc6ccccc6c5c3)c3ccc(C(C)(C)C)cc3-c3ccccc3)c3cc5oc6ccccc6c5cc31)Oc1ccccc1O4)C(C)(C)CCC2(C)C ; Cc1cc2c(cc1N1c3cc4c(cc3B(N(c3ccc(C(C)(C)C)cc3-c3ccccc3)c3cccc5c3sc3ccccc35)c3cc5oc6ccccc6c5cc31)Oc1ccccc1O4)C(C)(C)CCC2(C)C ; Cc1cc2c(cc1N1c3cc4c(cc3B(N(c3ccc(C(C)(C)C)cc3-c3ccccc3)c3cccc5sc6ccccc6c35)c3cc5oc6ccccc6c5cc31)Oc1ccccc1O4)C(C)(C)CCC2(C)C] 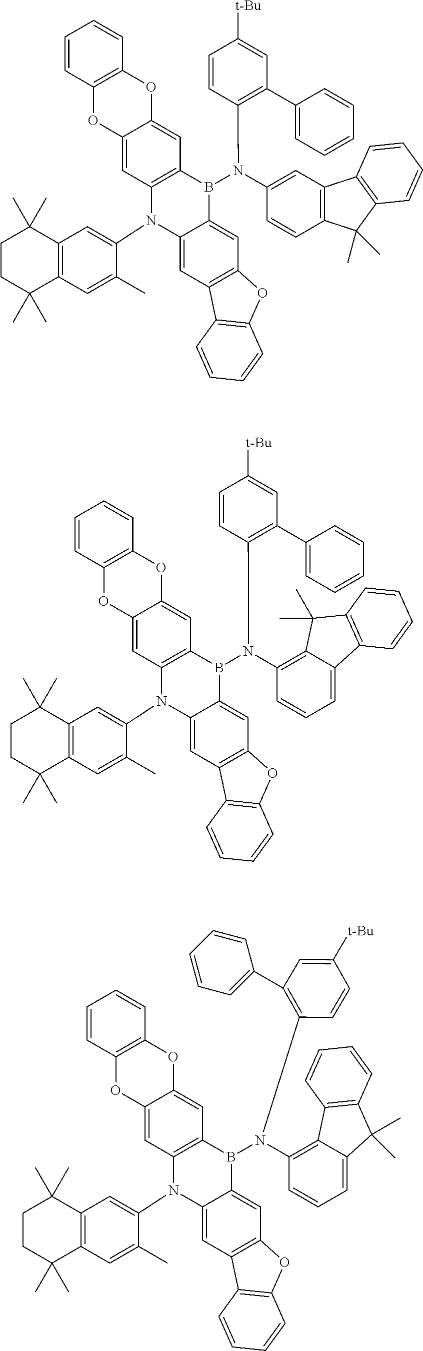 [SMILES: Cc1cc2c(cc1N1c3cc4c(cc3B(N(c3ccc5c(c3)-c3ccccc3C5(C)C)c3ccc(C(C)(C)C)cc3-c3ccccc3)c3cc5oc6ccccc6c5cc31)Oc1ccccc1O4)C(C)(C)CCC2(C)C ; Cc1cc2c(cc1N1c3cc4c(cc3B(N(c3ccc(C(C)(C)C)cc3-c3ccccc3)c3cccc5c3C(C)(C)c3ccccc3-5)c3cc5oc6ccccc6c5cc31)Oc1ccccc1O4)C(C)(C)CCC2(C)C ; Cc1cc2c(cc1N1c3cc4c(cc3B(N(c3ccc(C(C)(C)C)cc3-c3ccccc3)c3cccc5c3-c3ccccc3C5(C)C)c3cc5oc6ccccc6c5cc31)Oc1ccccc1O4)C(C)(C)CCC2(C)C] 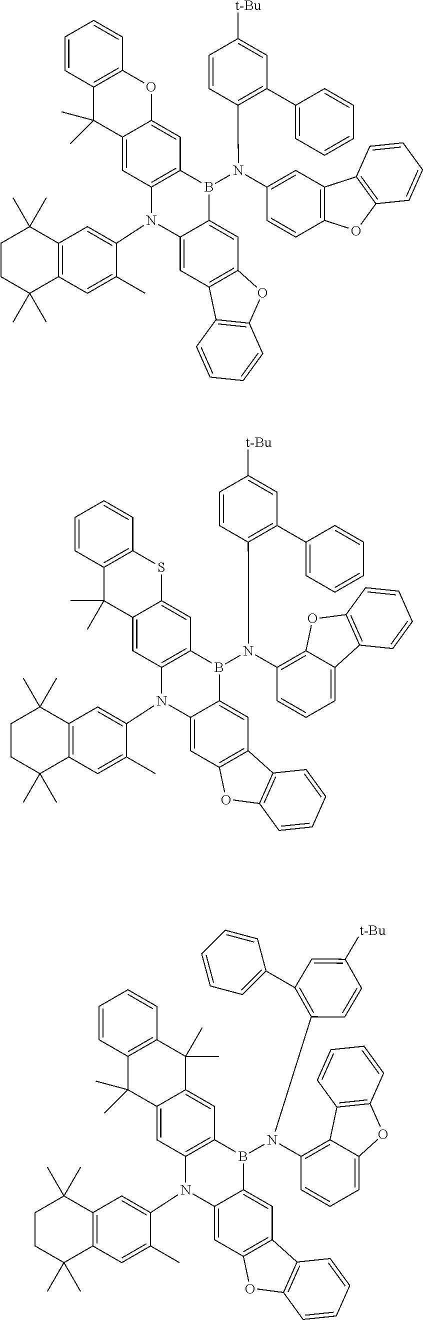 [SMILES: Cc1cc2c(cc1N1c3cc4c(cc3B(N(c3ccc5oc6ccccc6c5c3)c3ccc(C(C)(C)C)cc3-c3ccccc3)c3cc5oc6ccccc6c5cc31)Oc1ccccc1C4(C)C)C(C)(C)CCC2(C)C ; Cc1cc2c(cc1N1c3cc4c(cc3B(N(c3ccc(C(C)(C)C)cc3-c3ccccc3)c3cccc5c3oc3ccccc35)c3cc5c(cc31)oc1ccccc15)Sc1ccccc1C4(C)C)C(C)(C)CCC2(C)C ; Cc1cc2c(cc1N1c3cc4c(cc3B(N(c3ccc(C(C)(C)C)cc3-c3ccccc3)c3cccc5oc6ccccc6c35)c3cc5c(cc31)oc1ccccc15)C(C)(C)c1ccccc1C4(C)C)C(C)(C)CCC2(C)C] 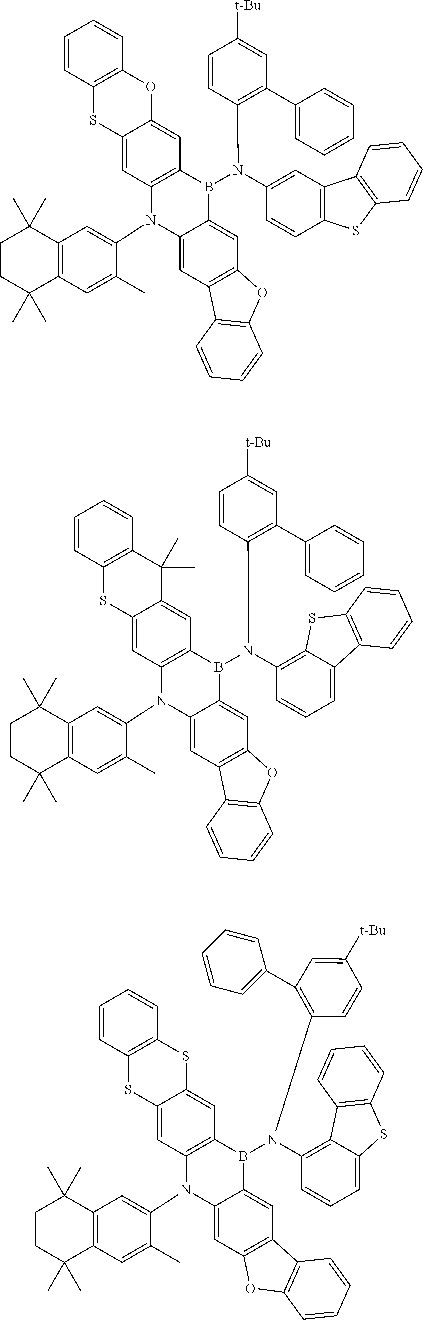 [SMILES: Cc1cc2c(cc1N1c3cc4c(cc3B(N(c3ccc5sc6ccccc6c5c3)c3ccc(C(C)(C)C)cc3-c3ccccc3)c3cc5oc6ccccc6c5cc31)Oc1ccccc1S4)C(C)(C)CCC2(C)C ; Cc1cc2c(cc1N1c3cc4c(cc3B(N(c3ccc(C(C)(C)C)cc3-c3ccccc3)c3cccc5c3sc3ccccc35)c3cc5oc6ccccc6c5cc31)C(C)(C)c1ccccc1S4)C(C)(C)CCC2(C)C ; Cc1cc2c(cc1N1c3cc4c(cc3B(N(c3ccc(C(C)(C)C)cc3-c3ccccc3)c3cccc5sc6ccccc6c35)c3cc5c(cc31)oc1ccccc15)Sc1ccccc1S4)C(C)(C)CCC2(C)C] 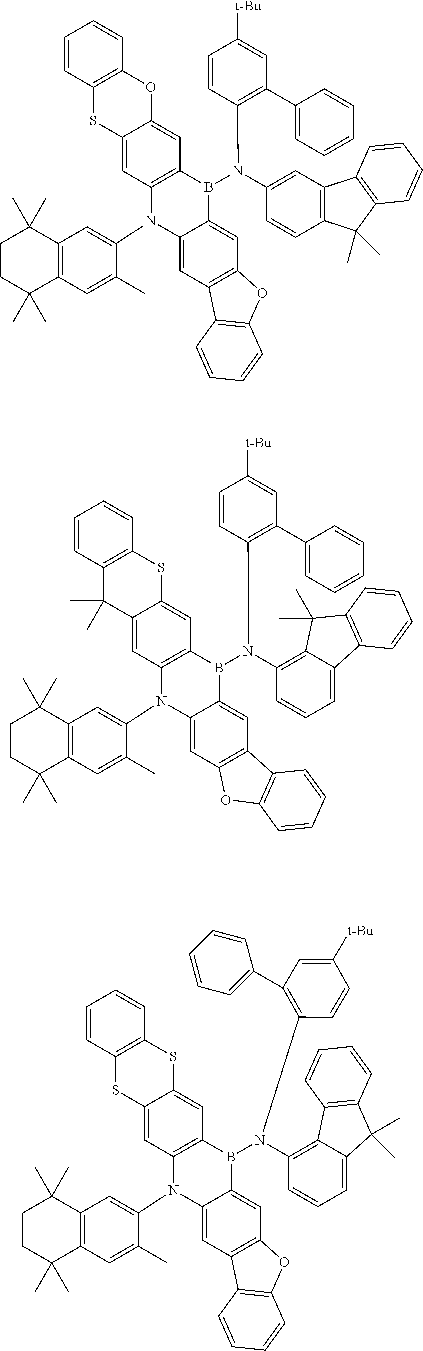 [SMILES: Cc1cc2c(cc1N1c3cc4c(cc3B(N(c3ccc5c(c3)-c3ccccc3C5(C)C)c3ccc(C(C)(C)C)cc3-c3ccccc3)c3cc5oc6ccccc6c5cc31)Oc1ccccc1S4)C(C)(C)CCC2(C)C ; Cc1cc2c(cc1N1c3cc4c(cc3B(N(c3ccc(C(C)(C)C)cc3-c3ccccc3)c3cccc5c3C(C)(C)c3ccccc3-5)c3cc5c(cc31)oc1ccccc15)Sc1ccccc1C4(C)C)C(C)(C)CCC2(C)C ; Cc1cc2c(cc1N1c3cc4c(cc3B(N(c3ccc(C(C)(C)C)cc3-c3ccccc3)c3cccc5c3-c3ccccc3C5(C)C)c3cc5oc6ccccc6c5cc31)Sc1ccccc1S4)C(C)(C)CCC2(C)C] 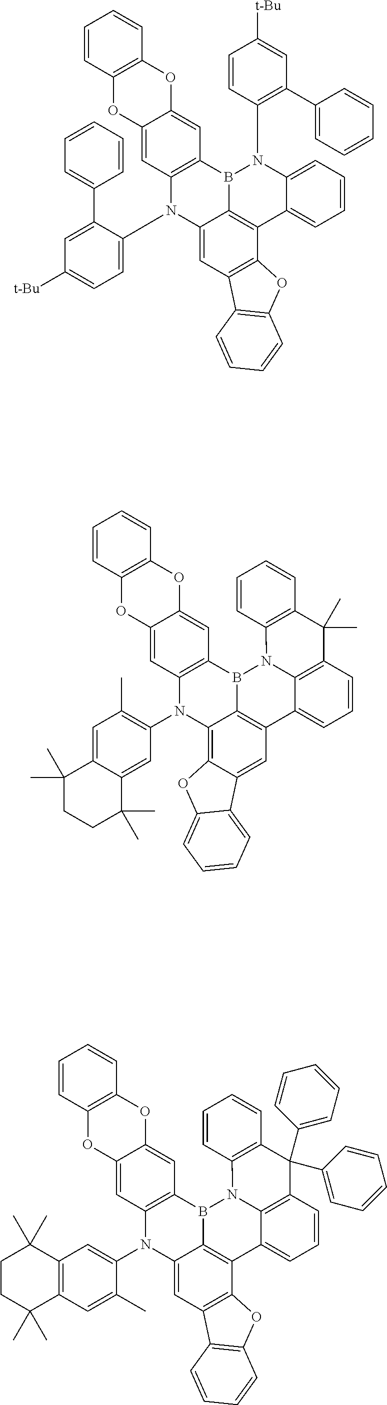 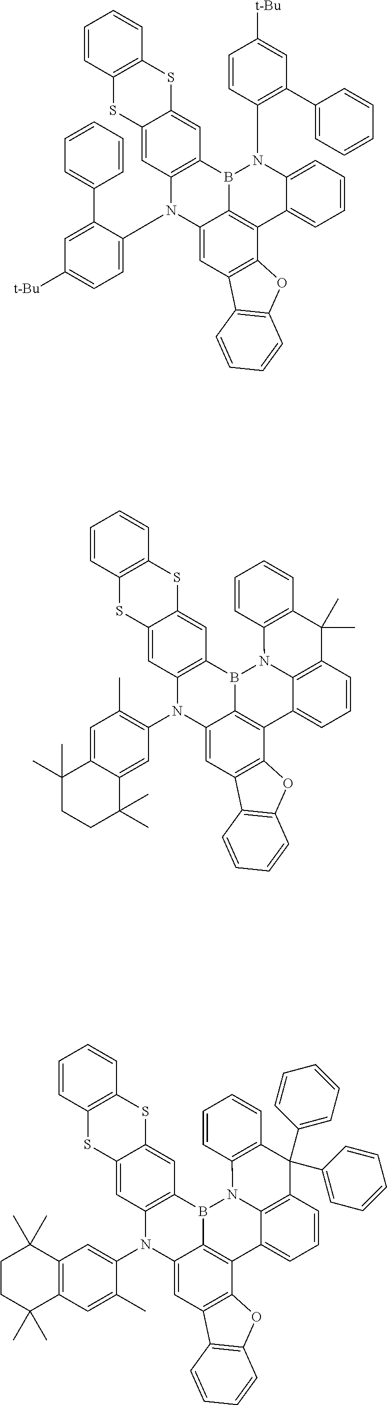 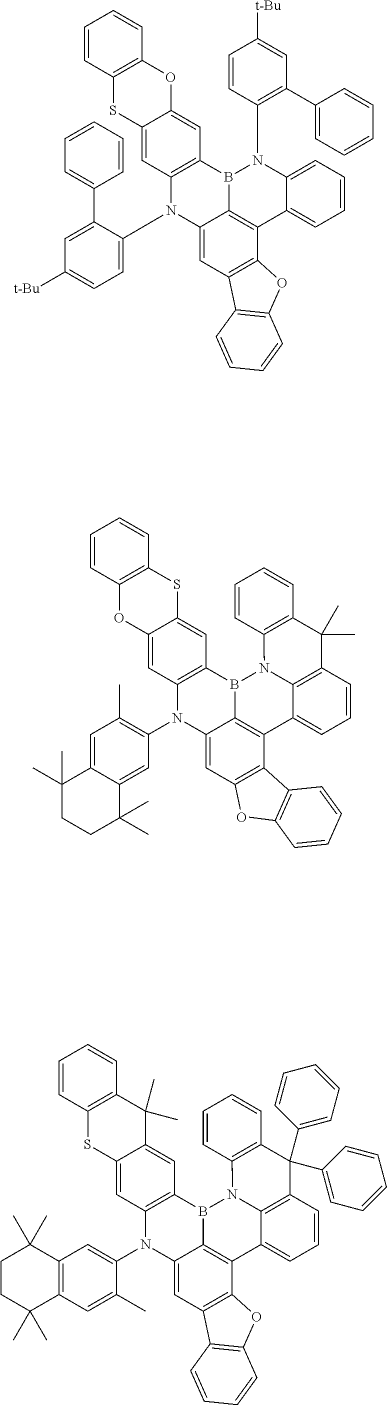 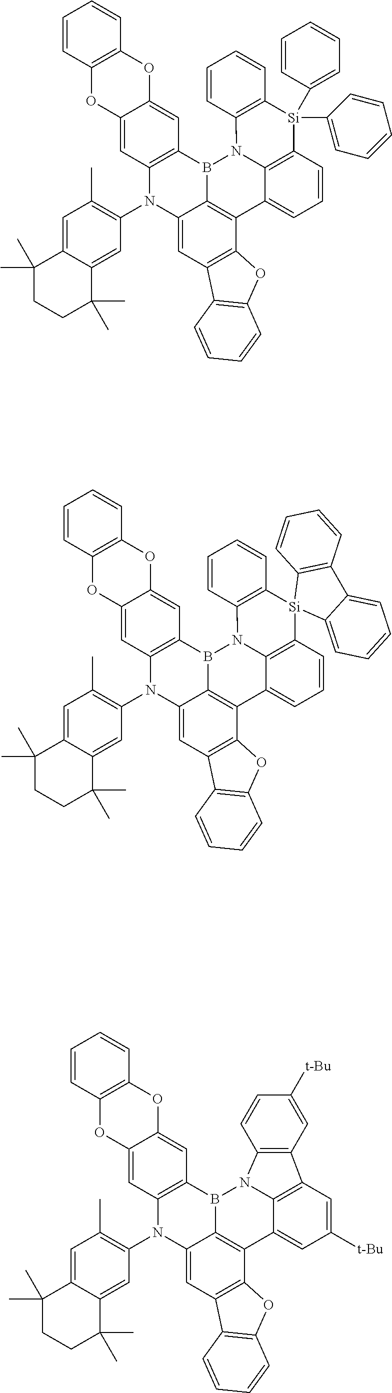 [SMILES: Cc1cc2c(cc1N1c3cc4c(cc3B3c5c1cc1c(oc6ccccc61)c5-c1cccc5c1N3c1ccccc1[Si]5(c1ccccc1)c1ccccc1)Oc1ccccc1O4)C(C)(C)CCC2(C)C ; Cc1cc2c(cc1N1c3cc4c(cc3B3c5c1cc1c(oc6ccccc61)c5-c1cccc5c1N3c1ccccc1[Si]51c3ccccc3-c3ccccc31)Oc1ccccc1O4)C(C)(C)CCC2(C)C ; Cc1cc2c(cc1N1c3cc4c(cc3B3c5c1cc1c(oc6ccccc61)c5-c1cc(C(C)(C)C)cc5c6cc(C(C)(C)C)ccc6n3c15)Oc1ccccc1O4)C(C)(C)CCC2(C)C] 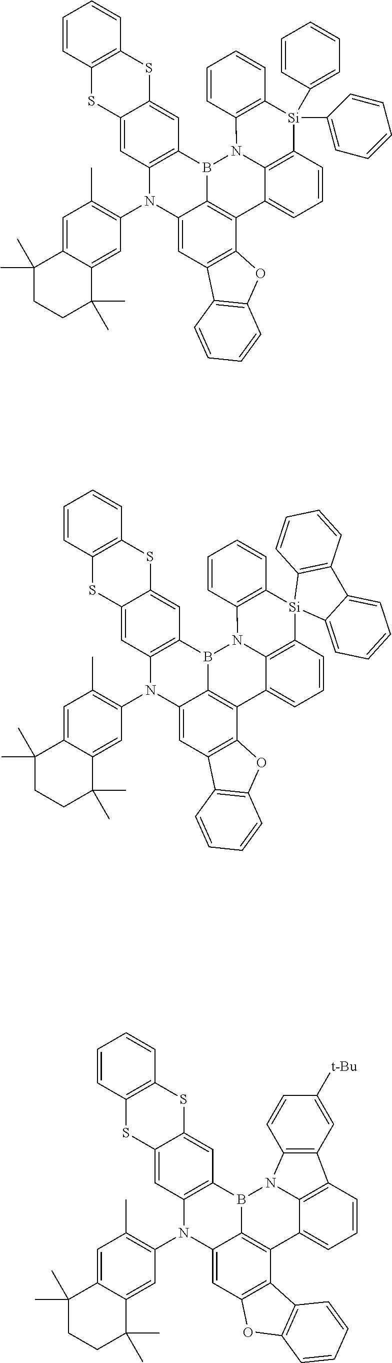 [SMILES: Cc1cc2c(cc1N1c3cc4c(cc3B3c5c1cc1c(oc6ccccc61)c5-c1cccc5c1N3c1ccccc1[Si]5(c1ccccc1)c1ccccc1)Sc1ccccc1S4)C(C)(C)CCC2(C)C ; Cc1cc2c(cc1N1c3cc4c(cc3B3c5c1cc1c(oc6ccccc61)c5-c1cccc5c1N3c1ccccc1[Si]51c3ccccc3-c3ccccc31)Sc1ccccc1S4)C(C)(C)CCC2(C)C ; Cc1cc2c(cc1N1c3cc4c(cc3B3c5c1cc1oc6ccccc6c1c5-c1cccc5c6cc(C(C)(C)C)ccc6n3c15)Sc1ccccc1S4)C(C)(C)CCC2(C)C] 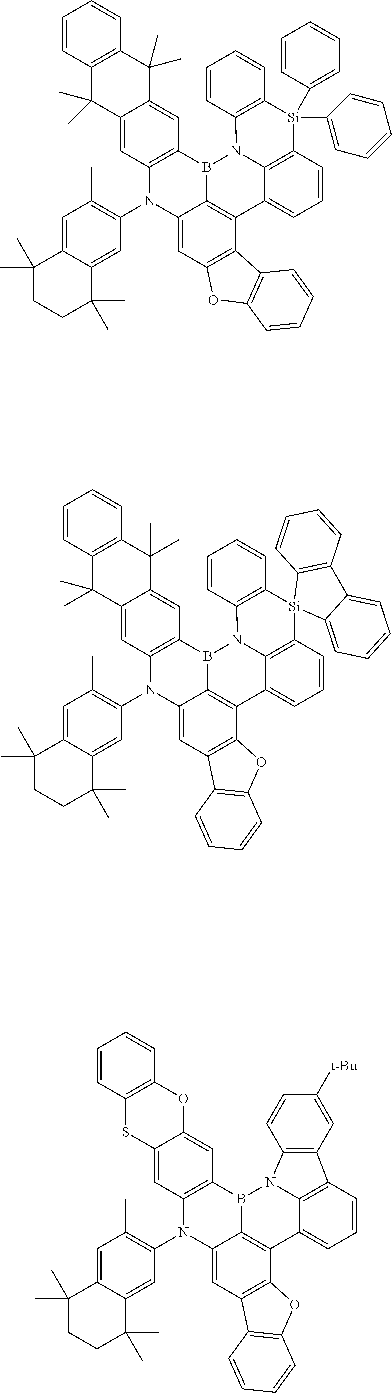 [SMILES: Cc1cc2c(cc1N1c3cc4c(cc3B3c5c1cc1oc6ccccc6c1c5-c1cccc5c1N3c1ccccc1[Si]5(c1ccccc1)c1ccccc1)C(C)(C)c1ccccc1C4(C)C)C(C)(C)CCC2(C)C ; Cc1cc2c(cc1N1c3cc4c(cc3B3c5c1cc1c(oc6ccccc61)c5-c1cccc5c1N3c1ccccc1[Si]51c3ccccc3-c3ccccc31)C(C)(C)c1ccccc1C4(C)C)C(C)(C)CCC2(C)C ; Cc1cc2c(cc1N1c3cc4c(cc3B3c5c1cc1c(oc6ccccc61)c5-c1cccc5c6cc(C(C)(C)C)ccc6n3c15)Oc1ccccc1S4)C(C)(C)CCC2(C)C] 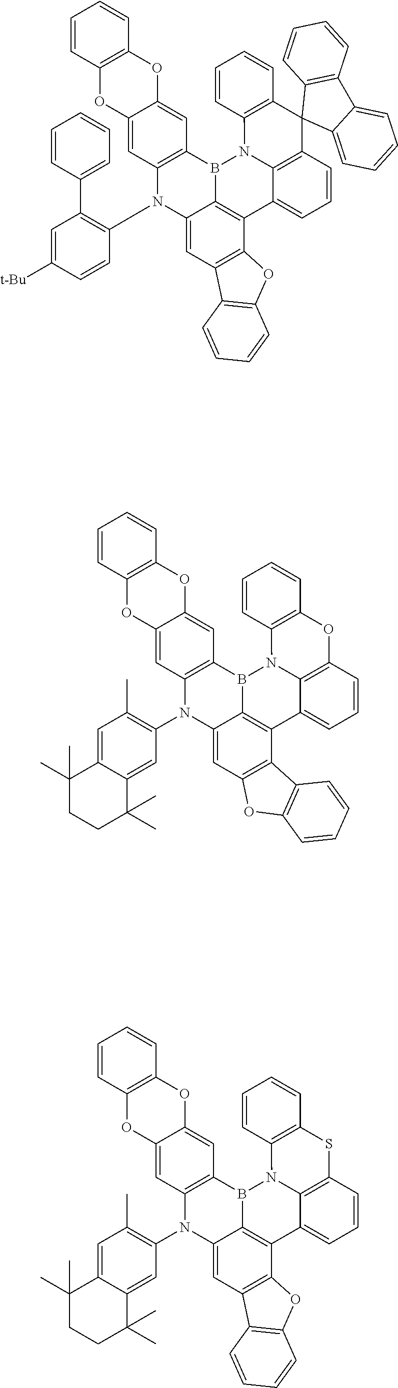 [SMILES: CC(C)(C)c1ccc(N2c3cc4c(cc3B3c5c2cc2c(oc6ccccc62)c5-c2cccc5c2N3c2ccccc2C52c3ccccc3-c3ccccc32)Oc2ccccc2O4)c(-c2ccccc2)c1 ; Cc1cc2c(cc1N1c3cc4c(cc3B3c5c1cc1oc6ccccc6c1c5-c1cccc5c1N3c1ccccc1O5)Oc1ccccc1O4)C(C)(C)CCC2(C)C ; Cc1cc2c(cc1N1c3cc4c(cc3B3c5c1cc1c(oc6ccccc61)c5-c1cccc5c1N3c1ccccc1S5)Oc1ccccc1O4)C(C)(C)CCC2(C)C] 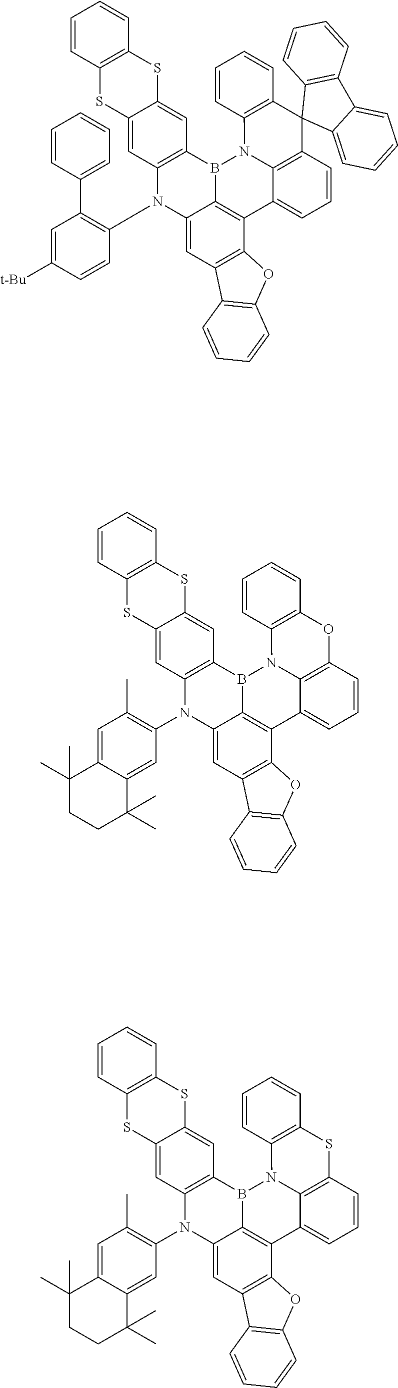 [SMILES: CC(C)(C)c1ccc(N2c3cc4c(cc3B3c5c2cc2c(oc6ccccc62)c5-c2cccc5c2N3c2ccccc2C52c3ccccc3-c3ccccc32)Sc2ccccc2S4)c(-c2ccccc2)c1 ; Cc1cc2c(cc1N1c3cc4c(cc3B3c5c1cc1c(oc6ccccc61)c5-c1cccc5c1N3c1ccccc1O5)Sc1ccccc1S4)C(C)(C)CCC2(C)C ; Cc1cc2c(cc1N1c3cc4c(cc3B3c5c1cc1c(oc6ccccc61)c5-c1cccc5c1N3c1ccccc1S5)Sc1ccccc1S4)C(C)(C)CCC2(C)C] 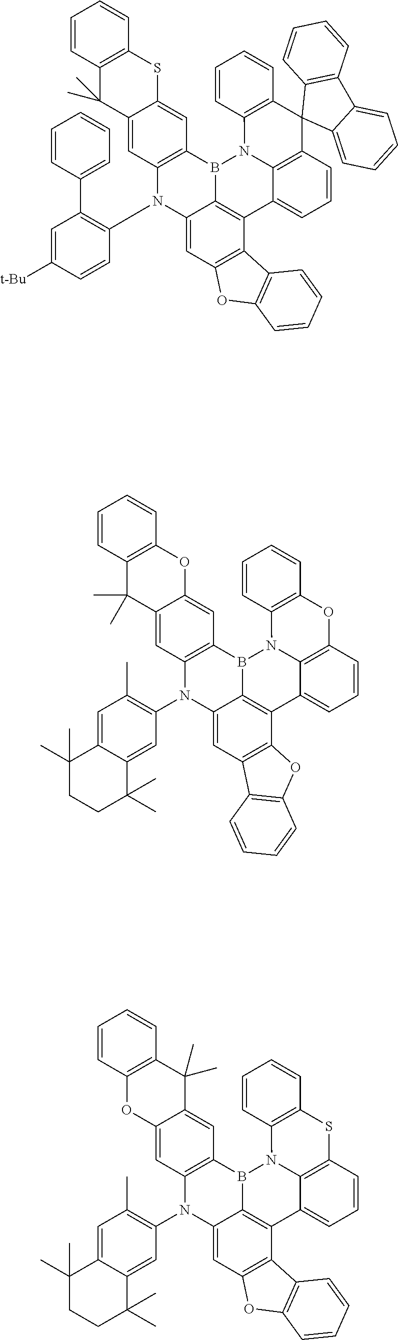 [SMILES: CC(C)(C)c1ccc(N2c3cc4c(cc3B3c5c2cc2oc6ccccc6c2c5-c2cccc5c2N3c2ccccc2C52c3ccccc3-c3ccccc32)Sc2ccccc2C4(C)C)c(-c2ccccc2)c1 ; Cc1cc2c(cc1N1c3cc4c(cc3B3c5c1cc1c(oc6ccccc61)c5-c1cccc5c1N3c1ccccc1O5)Oc1ccccc1C4(C)C)C(C)(C)CCC2(C)C ; Cc1cc2c(cc1N1c3cc4c(cc3B3c5c1cc1oc6ccccc6c1c5-c1cccc5c1N3c1ccccc1S5)C(C)(C)c1ccccc1O4)C(C)(C)CCC2(C)C] 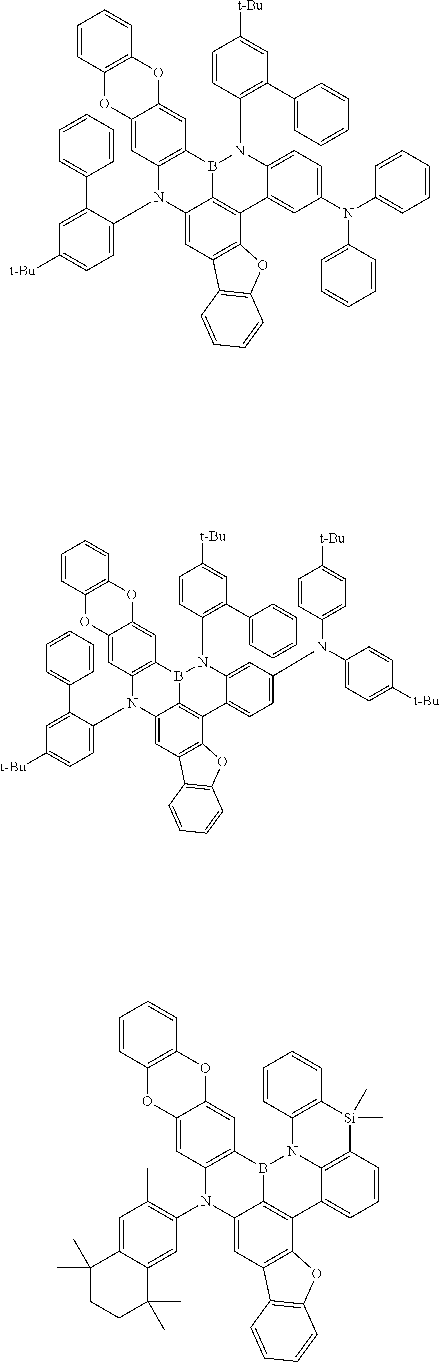 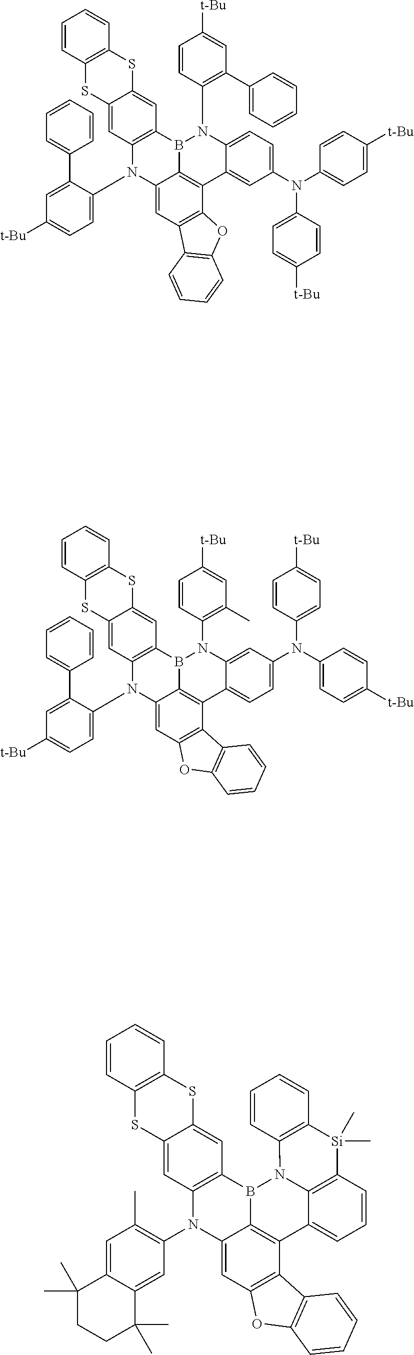 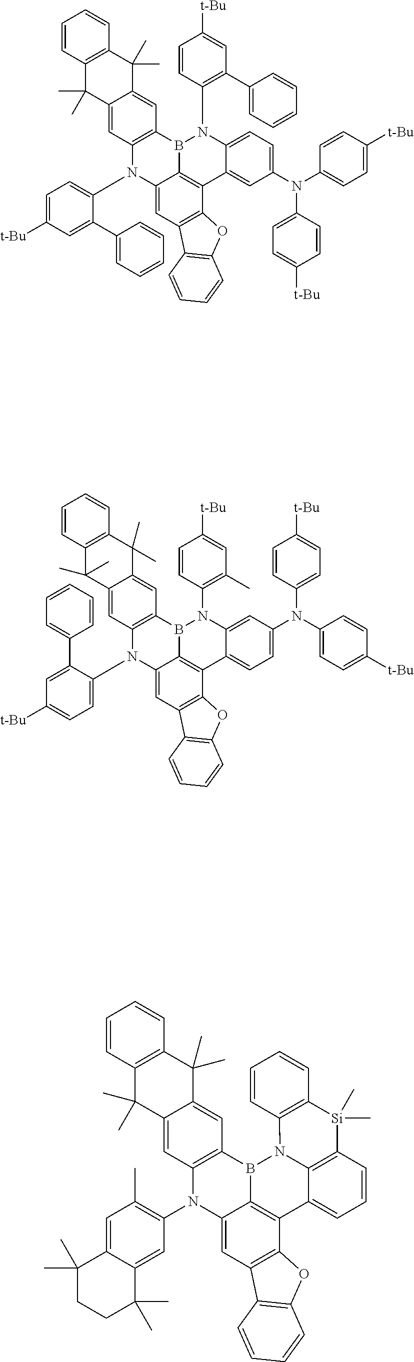 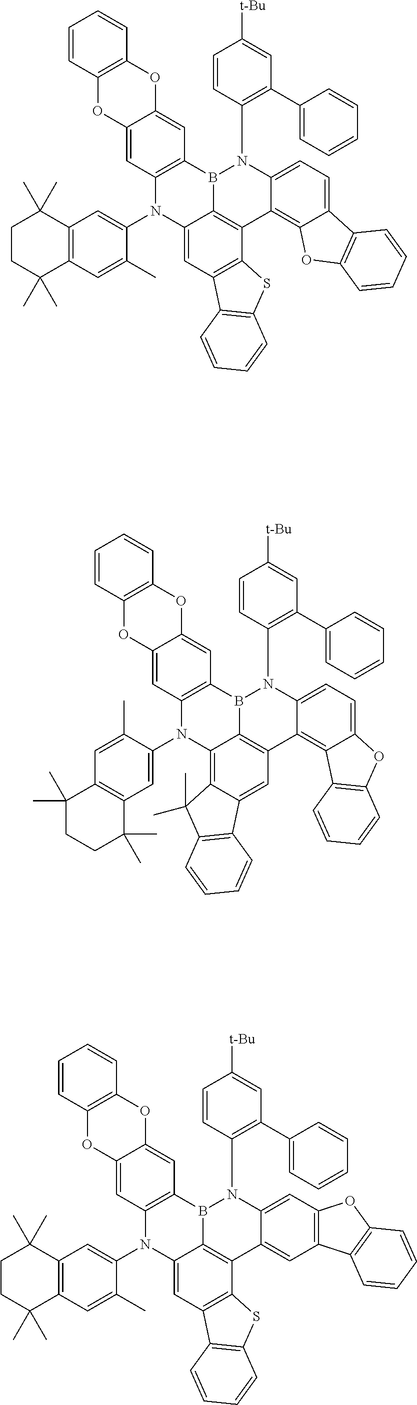 [SMILES: Cc1cc2c(cc1N1c3cc4c(cc3B3c5c1cc1c(sc6ccccc61)c5-c1c(ccc5c1oc1ccccc15)N3c1ccc(C(C)(C)C)cc1-c1ccccc1)Oc1ccccc1O4)C(C)(C)CCC2(C)C ; Cc1cc2c(cc1N1c3cc4c(cc3B3c5c(cc6c(c51)C(C)(C)c1ccccc1-6)-c1c(ccc5oc6ccccc6c15)N3c1ccc(C(C)(C)C)cc1-c1ccccc1)Oc1ccccc1O4)C(C)(C)CCC2(C)C ; Cc1cc2c(cc1N1c3cc4c(cc3B3c5c1cc1c(sc6ccccc61)c5-c1cc5c(cc1N3c1ccc(C(C)(C)C)cc1-c1ccccc1)oc1ccccc15)Oc1ccccc1O4)C(C)(C)CCC2(C)C] 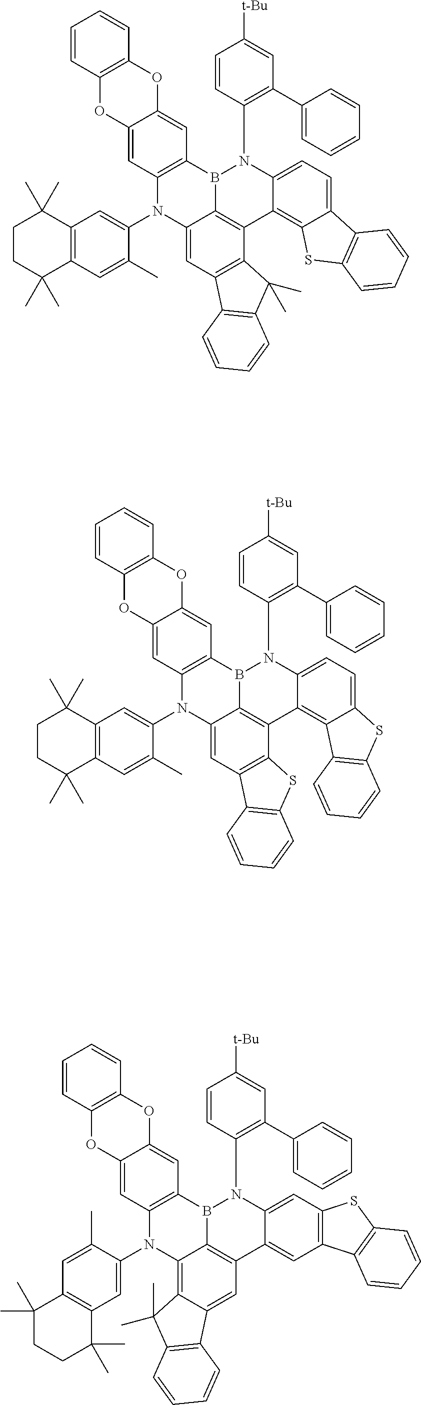 [SMILES: Cc1cc2c(cc1N1c3cc4c(cc3B3c5c1cc1c(c5-c5c(ccc6c5sc5ccccc56)N3c3ccc(C(C)(C)C)cc3-c3ccccc3)C(C)(C)c3ccccc3-1)Oc1ccccc1O4)C(C)(C)CCC2(C)C ; Cc1cc2c(cc1N1c3cc4c(cc3B3c5c1cc1c(sc6ccccc61)c5-c1c(ccc5sc6ccccc6c15)N3c1ccc(C(C)(C)C)cc1-c1ccccc1)Oc1ccccc1O4)C(C)(C)CCC2(C)C ; Cc1cc2c(cc1N1c3cc4c(cc3B3c5c(cc6c(c51)C(C)(C)c1ccccc1-6)-c1cc5c(cc1N3c1ccc(C(C)(C)C)cc1-c1ccccc1)sc1ccccc15)Oc1ccccc1O4)C(C)(C)CCC2(C)C] 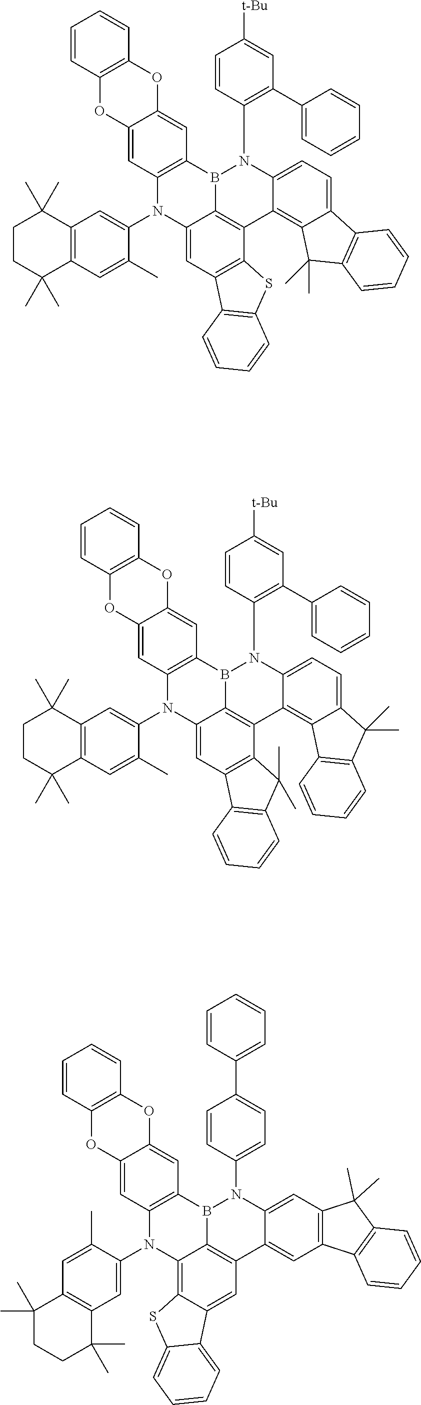 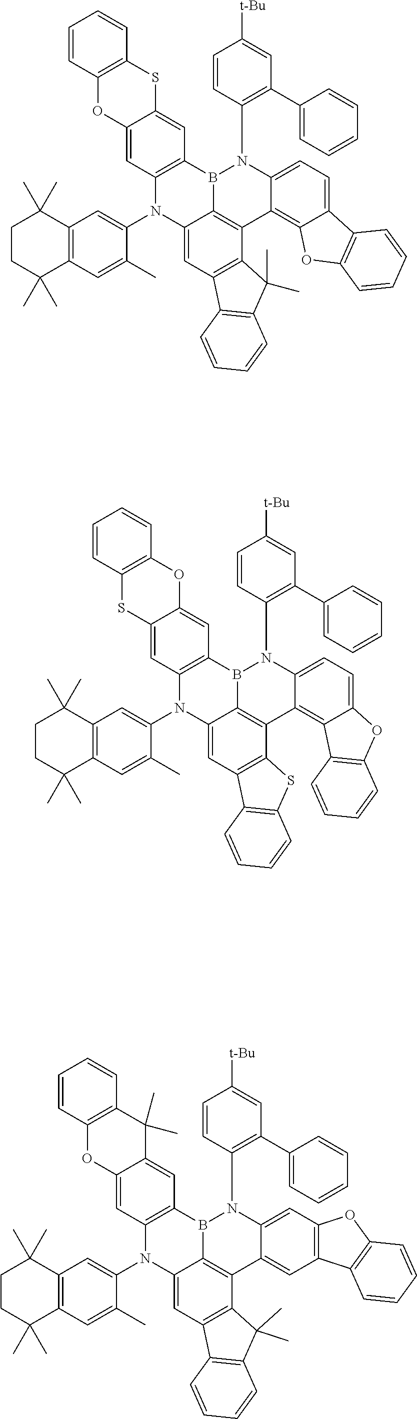 [SMILES: Cc1cc2c(cc1N1c3cc4c(cc3B3c5c1cc1c(c5-c5c(ccc6c5oc5ccccc56)N3c3ccc(C(C)(C)C)cc3-c3ccccc3)C(C)(C)c3ccccc3-1)Sc1ccccc1O4)C(C)(C)CCC2(C)C ; Cc1cc2c(cc1N1c3cc4c(cc3B3c5c1cc1c(sc6ccccc61)c5-c1c(ccc5oc6ccccc6c15)N3c1ccc(C(C)(C)C)cc1-c1ccccc1)Oc1ccccc1S4)C(C)(C)CCC2(C)C ; Cc1cc2c(cc1N1c3cc4c(cc3B3c5c1cc1c(c5-c5cc6c(cc5N3c3ccc(C(C)(C)C)cc3-c3ccccc3)oc3ccccc36)C(C)(C)c3ccccc3-1)C(C)(C)c1ccccc1O4)C(C)(C)CCC2(C)C] 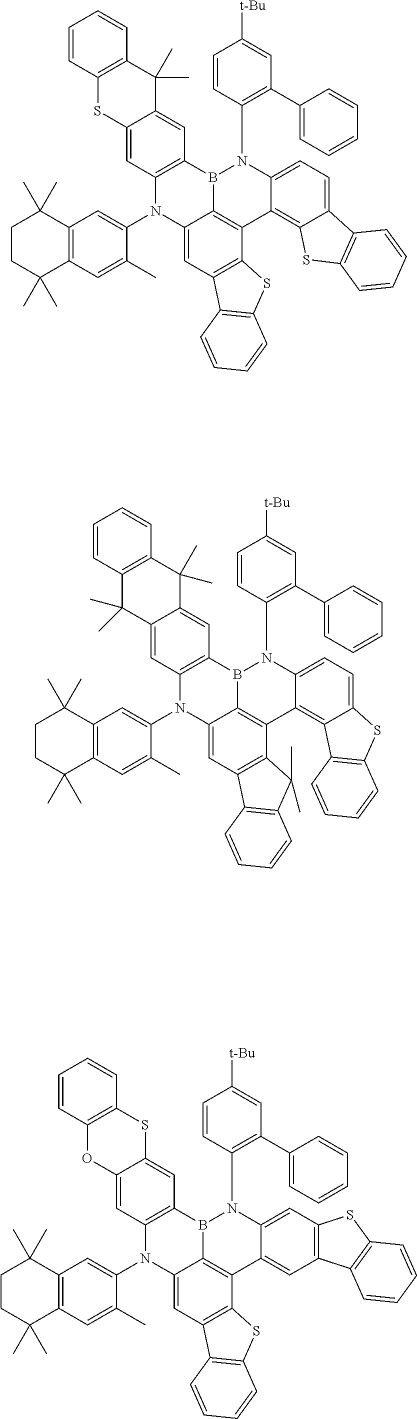 [SMILES: Cc1cc2c(cc1N1c3cc4c(cc3B3c5c1cc1c(sc6ccccc61)c5-c1c(ccc5c1sc1ccccc15)N3c1ccc(C(C)(C)C)cc1-c1ccccc1)C(C)(C)c1ccccc1S4)C(C)(C)CCC2(C)C ; Cc1cc2c(cc1N1c3cc4c(cc3B3c5c1cc1c(c5-c5c(ccc6sc7ccccc7c56)N3c3ccc(C(C)(C)C)cc3-c3ccccc3)C(C)(C)c3ccccc3-1)C(C)(C)c1ccccc1C4(C)C)C(C)(C)CCC2(C)C ; Cc1cc2c(cc1N1c3cc4c(cc3B3c5c1cc1c(sc6ccccc61)c5-c1cc5c(cc1N3c1ccc(C(C)(C)C)cc1-c1ccccc1)sc1ccccc15)Sc1ccccc1O4)C(C)(C)CCC2(C)C] 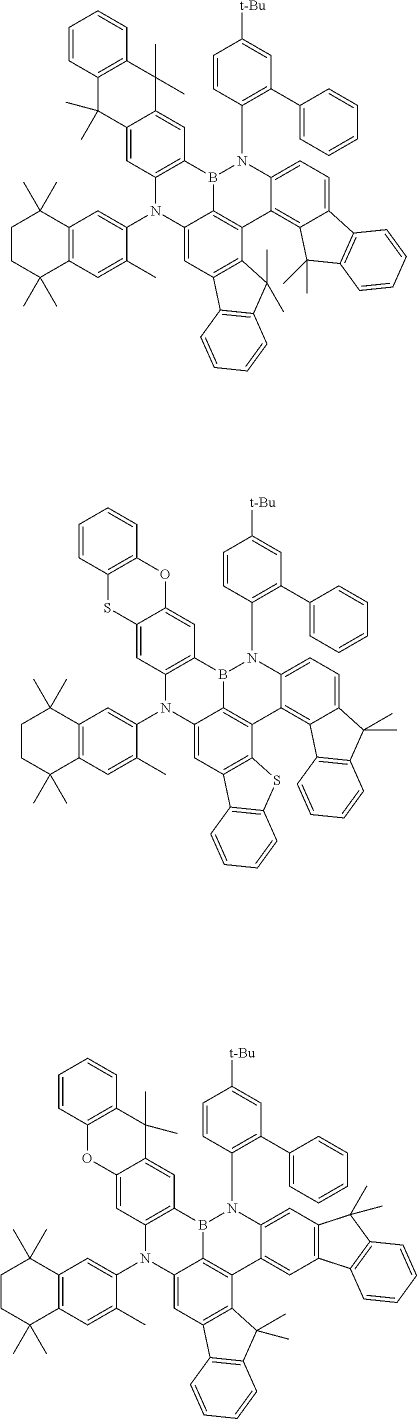 [SMILES: Cc1cc2c(cc1N1c3cc4c(cc3B3c5c1cc1c(c5-c5c(ccc6c5C(C)(C)c5ccccc5-6)N3c3ccc(C(C)(C)C)cc3-c3ccccc3)C(C)(C)c3ccccc3-1)C(C)(C)c1ccccc1C4(C)C)C(C)(C)CCC2(C)C ; Cc1cc2c(cc1N1c3cc4c(cc3B3c5c1cc1c(sc6ccccc61)c5-c1c(ccc5c1-c1ccccc1C5(C)C)N3c1ccc(C(C)(C)C)cc1-c1ccccc1)Oc1ccccc1S4)C(C)(C)CCC2(C)C ; Cc1cc2c(cc1N1c3cc4c(cc3B3c5c1cc1c(c5-c5cc6c(cc5N3c3ccc(C(C)(C)C)cc3-c3ccccc3)C(C)(C)c3ccccc3-6)C(C)(C)c3ccccc3-1)C(C)(C)c1ccccc1O4)C(C)(C)CCC2(C)C] 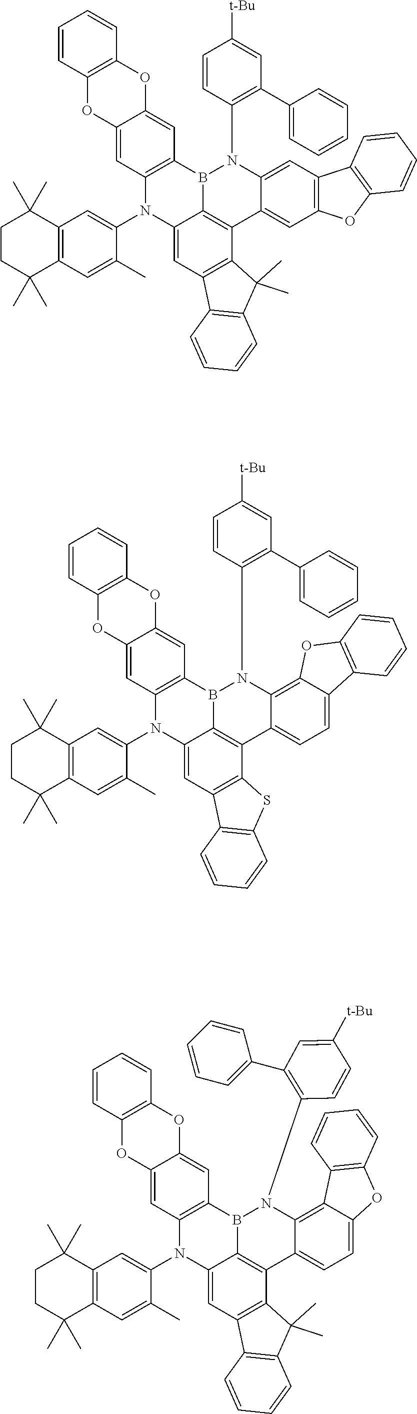 [SMILES: Cc1cc2c(cc1N1c3cc4c(cc3B3c5c1cc1c(c5-c5cc6oc7ccccc7c6cc5N3c3ccc(C(C)(C)C)cc3-c3ccccc3)C(C)(C)c3ccccc3-1)Oc1ccccc1O4)C(C)(C)CCC2(C)C ; Cc1cc2c(cc1N1c3cc4c(cc3B3c5c1cc1c(sc6ccccc61)c5-c1ccc5c(oc6ccccc65)c1N3c1ccc(C(C)(C)C)cc1-c1ccccc1)Oc1ccccc1O4)C(C)(C)CCC2(C)C ; Cc1cc2c(cc1N1c3cc4c(cc3B3c5c1cc1c(c5-c5ccc6oc7ccccc7c6c5N3c3ccc(C(C)(C)C)cc3-c3ccccc3)C(C)(C)c3ccccc3-1)Oc1ccccc1O4)C(C)(C)CCC2(C)C] 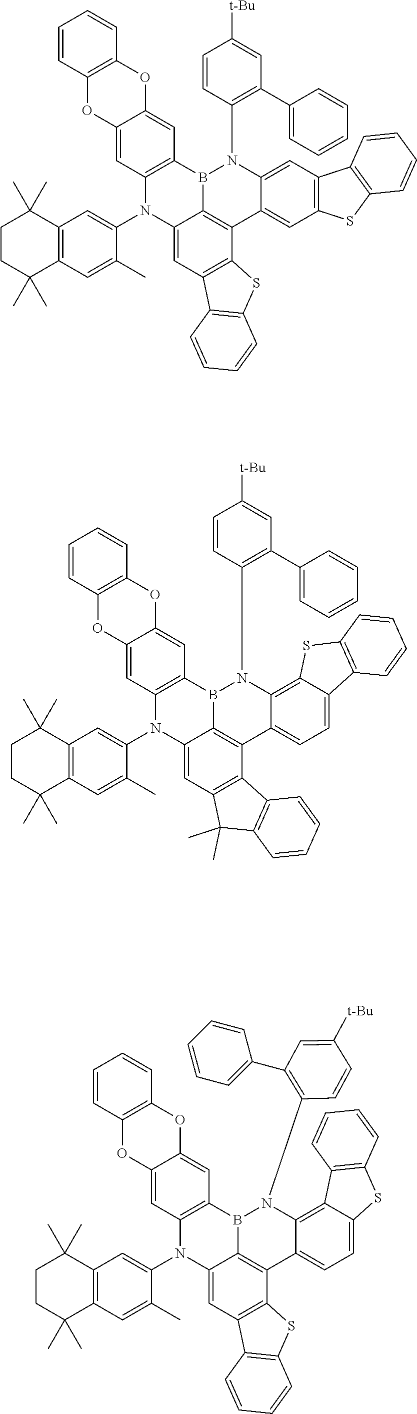 [SMILES: Cc1cc2c(cc1N1c3cc4c(cc3B3c5c1cc1c(sc6ccccc61)c5-c1cc5sc6ccccc6c5cc1N3c1ccc(C(C)(C)C)cc1-c1ccccc1)Oc1ccccc1O4)C(C)(C)CCC2(C)C ; Cc1cc2c(cc1N1c3cc4c(cc3B3c5c1cc1c(c5-c5ccc6c(sc7ccccc76)c5N3c3ccc(C(C)(C)C)cc3-c3ccccc3)-c3ccccc3C1(C)C)Oc1ccccc1O4)C(C)(C)CCC2(C)C ; Cc1cc2c(cc1N1c3cc4c(cc3B3c5c1cc1c(sc6ccccc61)c5-c1ccc5sc6ccccc6c5c1N3c1ccc(C(C)(C)C)cc1-c1ccccc1)Oc1ccccc1O4)C(C)(C)CCC2(C)C] 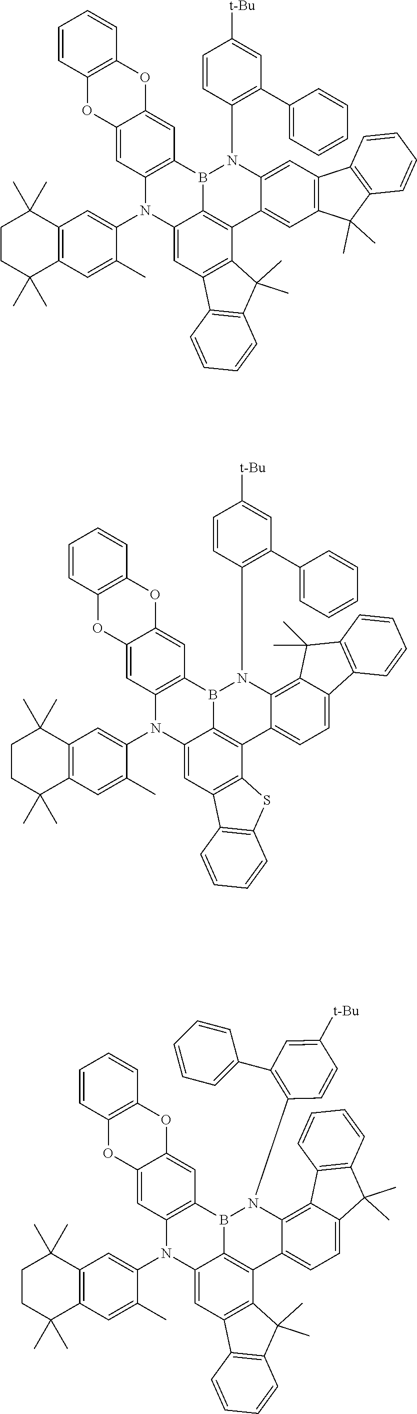 [SMILES: Cc1cc2c(cc1N1c3cc4c(cc3B3c5c1cc1c(c5-c5cc6c(cc5N3c3ccc(C(C)(C)C)cc3-c3ccccc3)-c3ccccc3C6(C)C)C(C)(C)c3ccccc3-1)Oc1ccccc1O4)C(C)(C)CCC2(C)C ; Cc1cc2c(cc1N1c3cc4c(cc3B3c5c1cc1c(sc6ccccc61)c5-c1ccc5c(c1N3c1ccc(C(C)(C)C)cc1-c1ccccc1)C(C)(C)c1ccccc1-5)Oc1ccccc1O4)C(C)(C)CCC2(C)C ; Cc1cc2c(cc1N1c3cc4c(cc3B3c5c1cc1c(c5-c5ccc6c(c5N3c3ccc(C(C)(C)C)cc3-c3ccccc3)-c3ccccc3C6(C)C)C(C)(C)c3ccccc3-1)Oc1ccccc1O4)C(C)(C)CCC2(C)C] 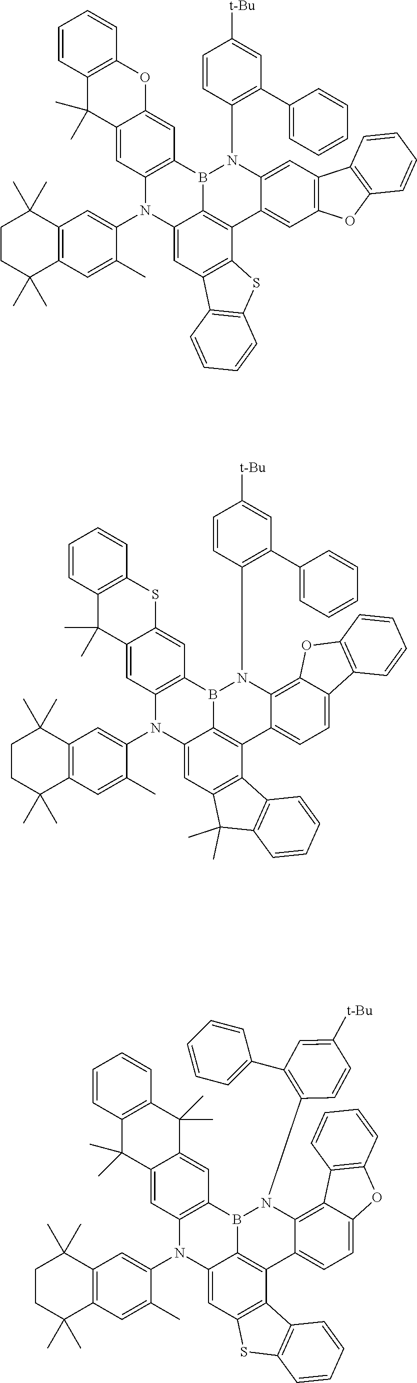 [SMILES: Cc1cc2c(cc1N1c3cc4c(cc3B3c5c1cc1c(sc6ccccc61)c5-c1cc5oc6ccccc6c5cc1N3c1ccc(C(C)(C)C)cc1-c1ccccc1)Oc1ccccc1C4(C)C)C(C)(C)CCC2(C)C ; Cc1cc2c(cc1N1c3cc4c(cc3B3c5c1cc1c(c5-c5ccc6c(oc7ccccc76)c5N3c3ccc(C(C)(C)C)cc3-c3ccccc3)-c3ccccc3C1(C)C)Sc1ccccc1C4(C)C)C(C)(C)CCC2(C)C ; Cc1cc2c(cc1N1c3cc4c(cc3B3c5c1cc1sc6ccccc6c1c5-c1ccc5oc6ccccc6c5c1N3c1ccc(C(C)(C)C)cc1-c1ccccc1)C(C)(C)c1ccccc1C4(C)C)C(C)(C)CCC2(C)C] 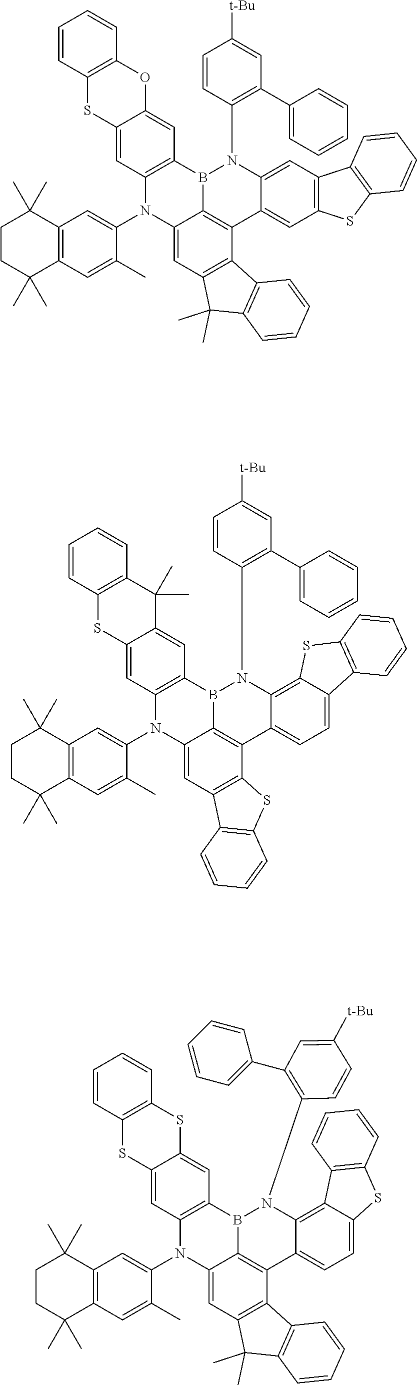 [SMILES: Cc1cc2c(cc1N1c3cc4c(cc3B3c5c1cc1c(c5-c5cc6sc7ccccc7c6cc5N3c3ccc(C(C)(C)C)cc3-c3ccccc3)-c3ccccc3C1(C)C)Oc1ccccc1S4)C(C)(C)CCC2(C)C ; Cc1cc2c(cc1N1c3cc4c(cc3B3c5c1cc1c(sc6ccccc61)c5-c1ccc5c(sc6ccccc65)c1N3c1ccc(C(C)(C)C)cc1-c1ccccc1)C(C)(C)c1ccccc1S4)C(C)(C)CCC2(C)C ; Cc1cc2c(cc1N1c3cc4c(cc3B3c5c1cc1c(c5-c5ccc6sc7ccccc7c6c5N3c3ccc(C(C)(C)C)cc3-c3ccccc3)-c3ccccc3C1(C)C)Sc1ccccc1S4)C(C)(C)CCC2(C)C] 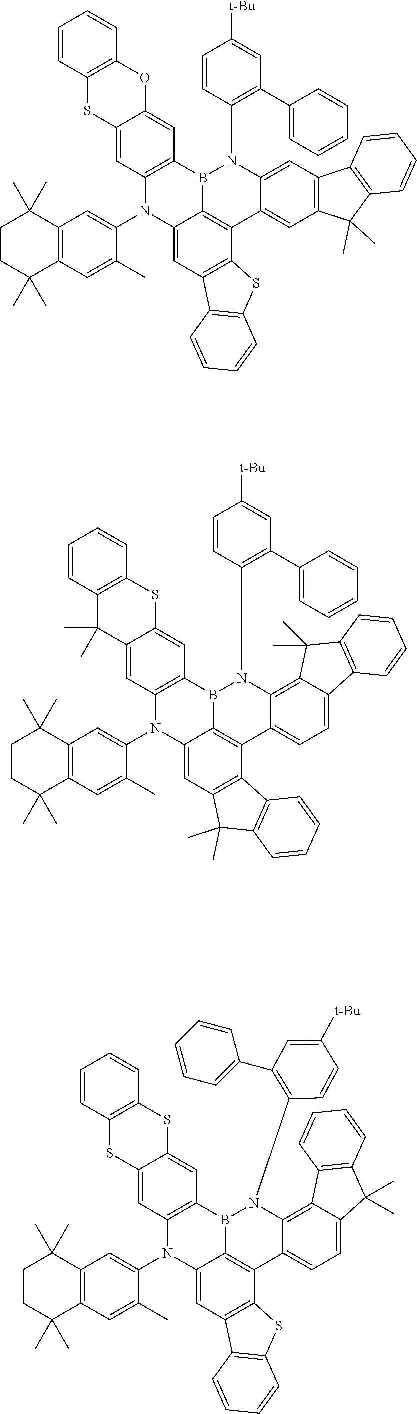 [SMILES: Cc1cc2c(cc1N1c3cc4c(cc3B3c5c1cc1c(sc6ccccc61)c5-c1cc5c(cc1N3c1ccc(C(C)(C)C)cc1-c1ccccc1)-c1ccccc1C5(C)C)Oc1ccccc1S4)C(C)(C)CCC2(C)C ; Cc1cc2c(cc1N1c3cc4c(cc3B3c5c1cc1c(c5-c5ccc6c(c5N3c3ccc(C(C)(C)C)cc3-c3ccccc3)C(C)(C)c3ccccc3-6)-c3ccccc3C1(C)C)Sc1ccccc1C4(C)C)C(C)(C)CCC2(C)C ; Cc1cc2c(cc1N1c3cc4c(cc3B3c5c1cc1c(sc6ccccc61)c5-c1ccc5c(c1N3c1ccc(C(C)(C)C)cc1-c1ccccc1)-c1ccccc1C5(C)C)Sc1ccccc1S4)C(C)(C)CCC2(C)C] 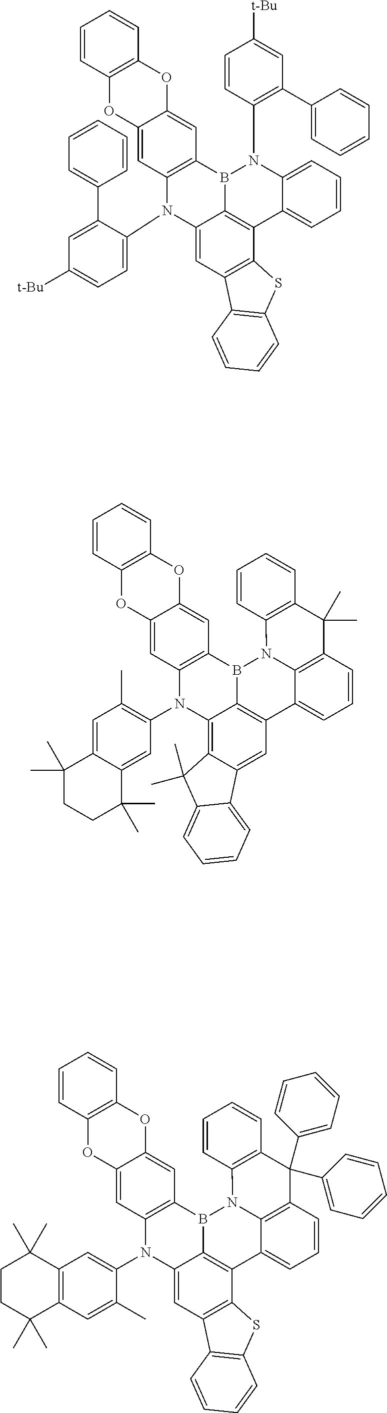 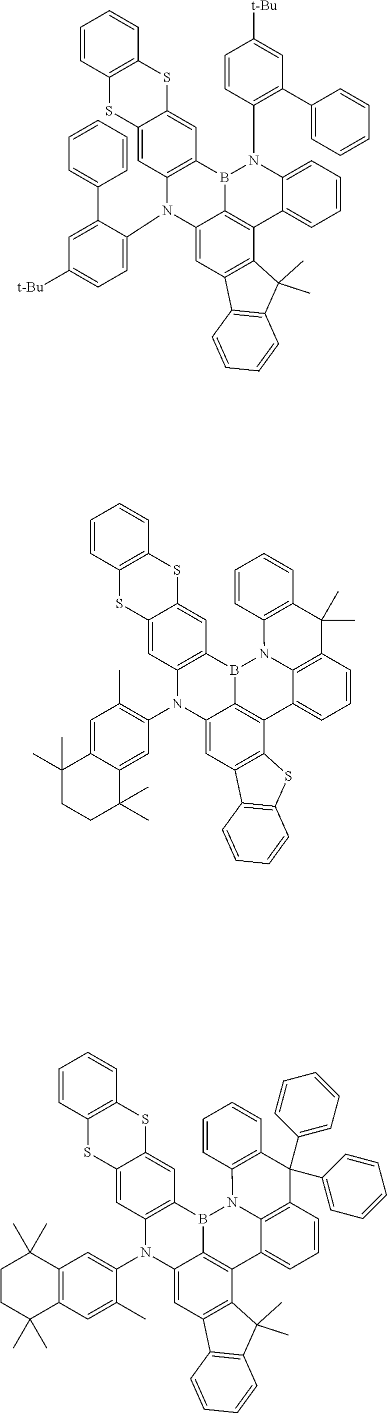 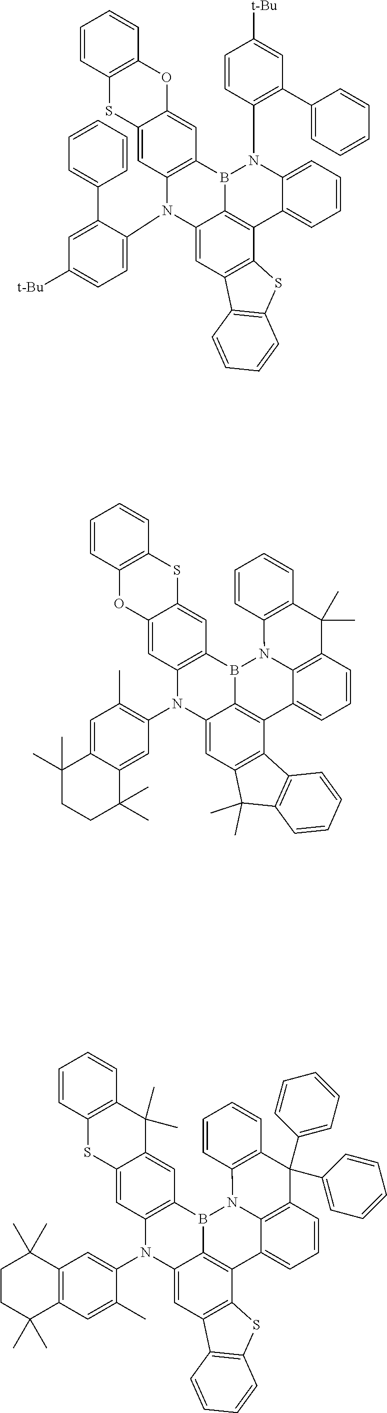 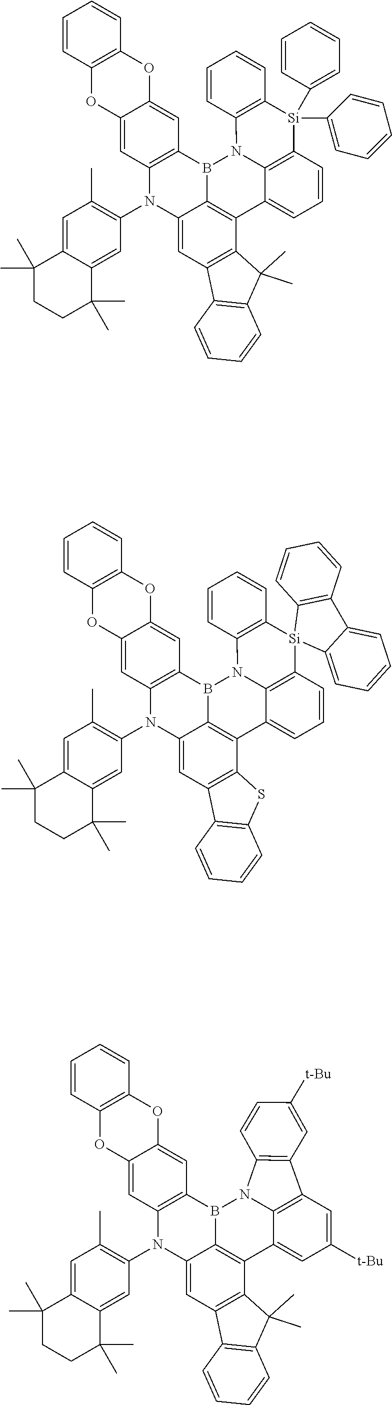 [SMILES: Cc1cc2c(cc1N1c3cc4c(cc3B3c5c1cc1c(c5-c5cccc6c5N3c3ccccc3[Si]6(c3ccccc3)c3ccccc3)C(C)(C)c3ccccc3-1)Oc1ccccc1O4)C(C)(C)CCC2(C)C ; Cc1cc2c(cc1N1c3cc4c(cc3B3c5c1cc1c(sc6ccccc61)c5-c1cccc5c1N3c1ccccc1[Si]51c3ccccc3-c3ccccc31)Oc1ccccc1O4)C(C)(C)CCC2(C)C ; Cc1cc2c(cc1N1c3cc4c(cc3B3c5c1cc1c(c5-c5cc(C(C)(C)C)cc6c7cc(C(C)(C)C)ccc7n3c56)C(C)(C)c3ccccc3-1)Oc1ccccc1O4)C(C)(C)CCC2(C)C] 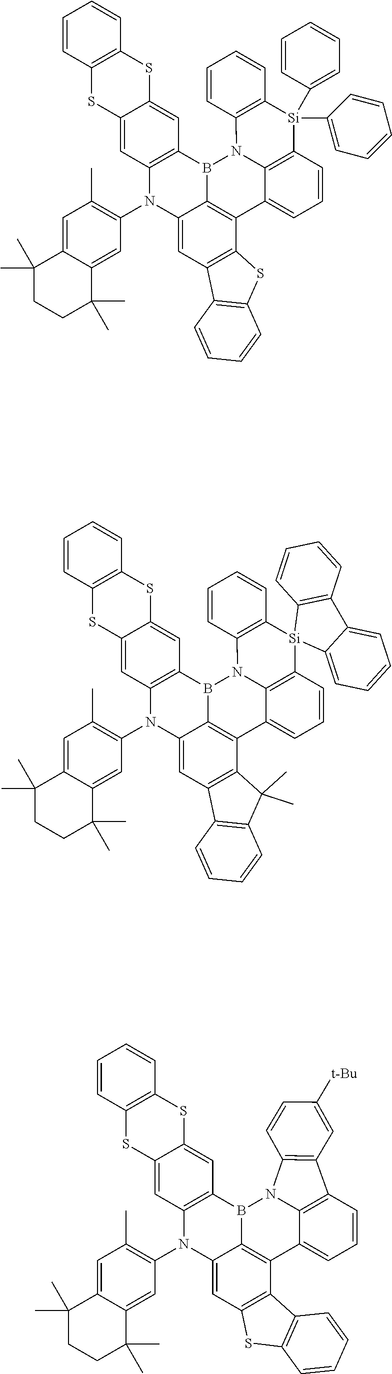 [SMILES: Cc1cc2c(cc1N1c3cc4c(cc3B3c5c1cc1c(sc6ccccc61)c5-c1cccc5c1N3c1ccccc1[Si]5(c1ccccc1)c1ccccc1)Sc1ccccc1S4)C(C)(C)CCC2(C)C ; Cc1cc2c(cc1N1c3cc4c(cc3B3c5c1cc1c(c5-c5cccc6c5N3c3ccccc3[Si]63c5ccccc5-c5ccccc53)C(C)(C)c3ccccc3-1)Sc1ccccc1S4)C(C)(C)CCC2(C)C ; Cc1cc2c(cc1N1c3cc4c(cc3B3c5c1cc1sc6ccccc6c1c5-c1cccc5c6cc(C(C)(C)C)ccc6n3c15)Sc1ccccc1S4)C(C)(C)CCC2(C)C] 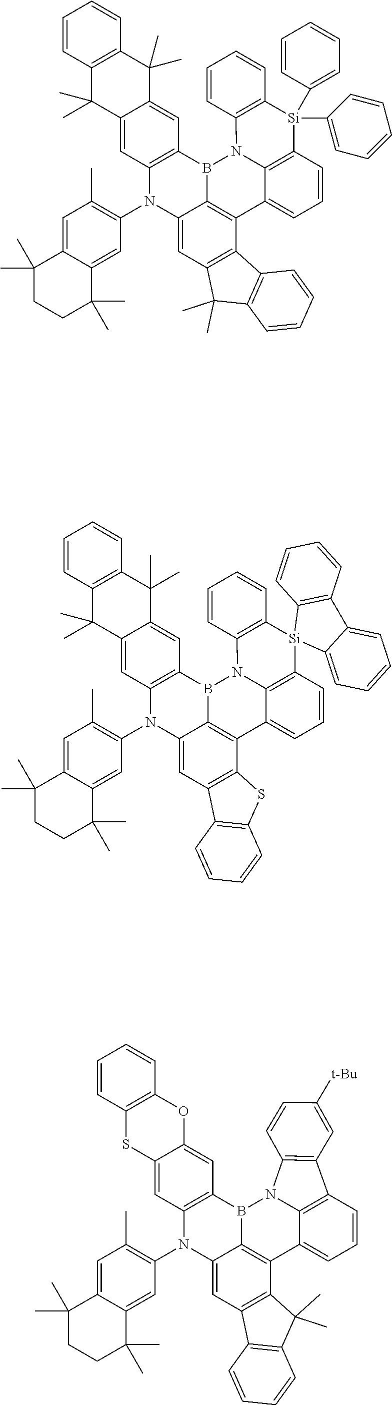 [SMILES: Cc1cc2c(cc1N1c3cc4c(cc3B3c5c1cc1c(c5-c5cccc6c5N3c3ccccc3[Si]6(c3ccccc3)c3ccccc3)-c3ccccc3C1(C)C)C(C)(C)c1ccccc1C4(C)C)C(C)(C)CCC2(C)C ; Cc1cc2c(cc1N1c3cc4c(cc3B3c5c1cc1c(sc6ccccc61)c5-c1cccc5c1N3c1ccccc1[Si]51c3ccccc3-c3ccccc31)C(C)(C)c1ccccc1C4(C)C)C(C)(C)CCC2(C)C ; Cc1cc2c(cc1N1c3cc4c(cc3B3c5c1cc1c(c5-c5cccc6c7cc(C(C)(C)C)ccc7n3c56)C(C)(C)c3ccccc3-1)Oc1ccccc1S4)C(C)(C)CCC2(C)C] 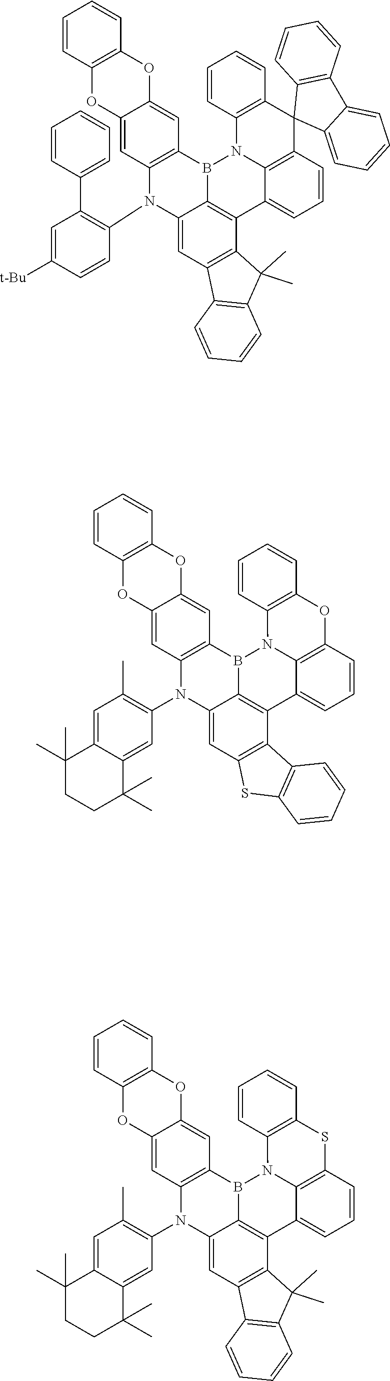 [SMILES: CC(C)(C)c1ccc(N2c3cc4c(cc3B3c5c2cc2c(c5-c5cccc6c5N3c3ccccc3C63c5ccccc5-c5ccccc53)C(C)(C)c3ccccc3-2)Oc2ccccc2O4)c(-c2ccccc2)c1 ; Cc1cc2c(cc1N1c3cc4c(cc3B3c5c1cc1sc6ccccc6c1c5-c1cccc5c1N3c1ccccc1O5)Oc1ccccc1O4)C(C)(C)CCC2(C)C ; Cc1cc2c(cc1N1c3cc4c(cc3B3c5c1cc1c(c5-c5cccc6c5N3c3ccccc3S6)C(C)(C)c3ccccc3-1)Oc1ccccc1O4)C(C)(C)CCC2(C)C] 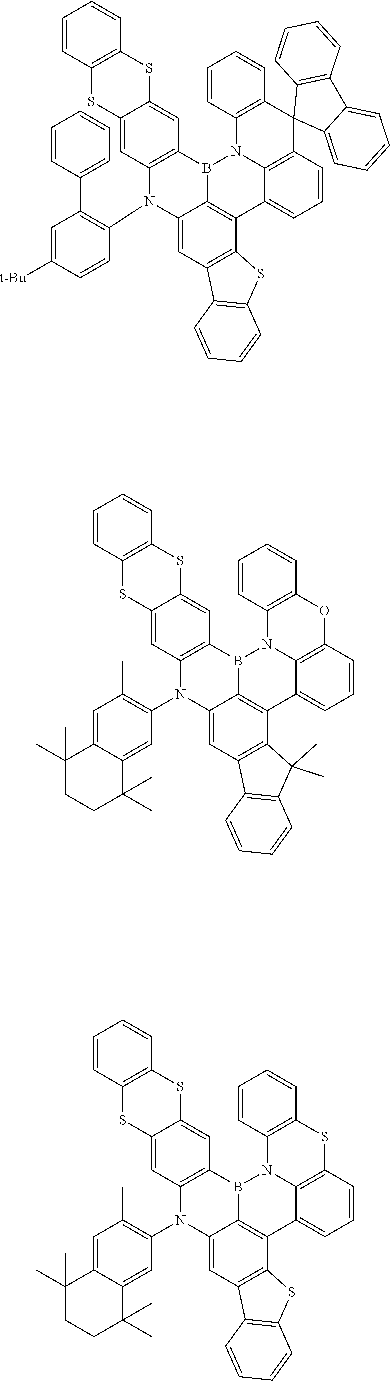 [SMILES: CC(C)(C)c1ccc(N2c3cc4c(cc3B3c5c2cc2c(sc6ccccc62)c5-c2cccc5c2N3c2ccccc2C52c3ccccc3-c3ccccc32)Sc2ccccc2S4)c(-c2ccccc2)c1 ; Cc1cc2c(cc1N1c3cc4c(cc3B3c5c1cc1c(c5-c5cccc6c5N3c3ccccc3O6)C(C)(C)c3ccccc3-1)Sc1ccccc1S4)C(C)(C)CCC2(C)C ; Cc1cc2c(cc1N1c3cc4c(cc3B3c5c1cc1c(sc6ccccc61)c5-c1cccc5c1N3c1ccccc1S5)Sc1ccccc1S4)C(C)(C)CCC2(C)C] 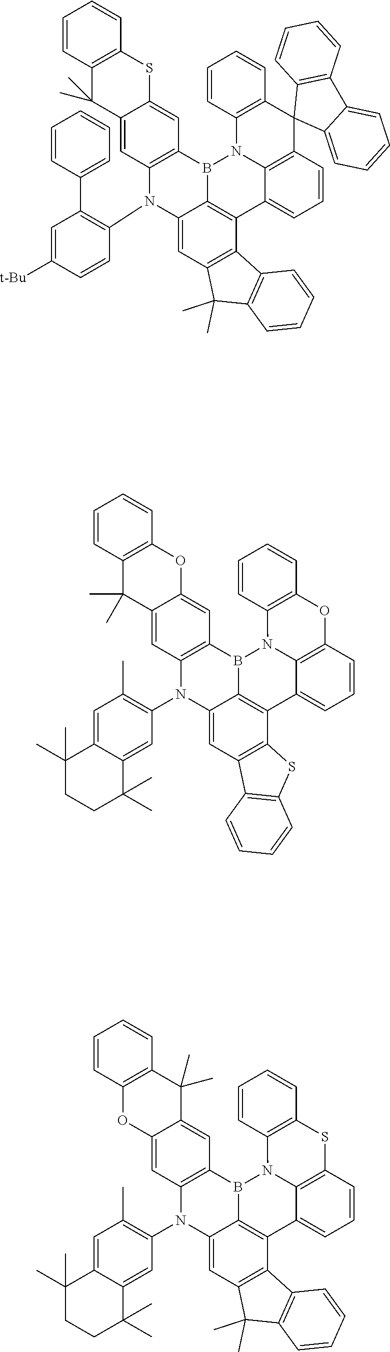 [SMILES: CC(C)(C)c1ccc(N2c3cc4c(cc3B3c5c2cc2c(c5-c5cccc6c5N3c3ccccc3C63c5ccccc5-c5ccccc53)-c3ccccc3C2(C)C)Sc2ccccc2C4(C)C)c(-c2ccccc2)c1 ; Cc1cc2c(cc1N1c3cc4c(cc3B3c5c1cc1c(sc6ccccc61)c5-c1cccc5c1N3c1ccccc1O5)Oc1ccccc1C4(C)C)C(C)(C)CCC2(C)C ; Cc1cc2c(cc1N1c3cc4c(cc3B3c5c1cc1c(c5-c5cccc6c5N3c3ccccc3S6)-c3ccccc3C1(C)C)C(C)(C)c1ccccc1O4)C(C)(C)CCC2(C)C] 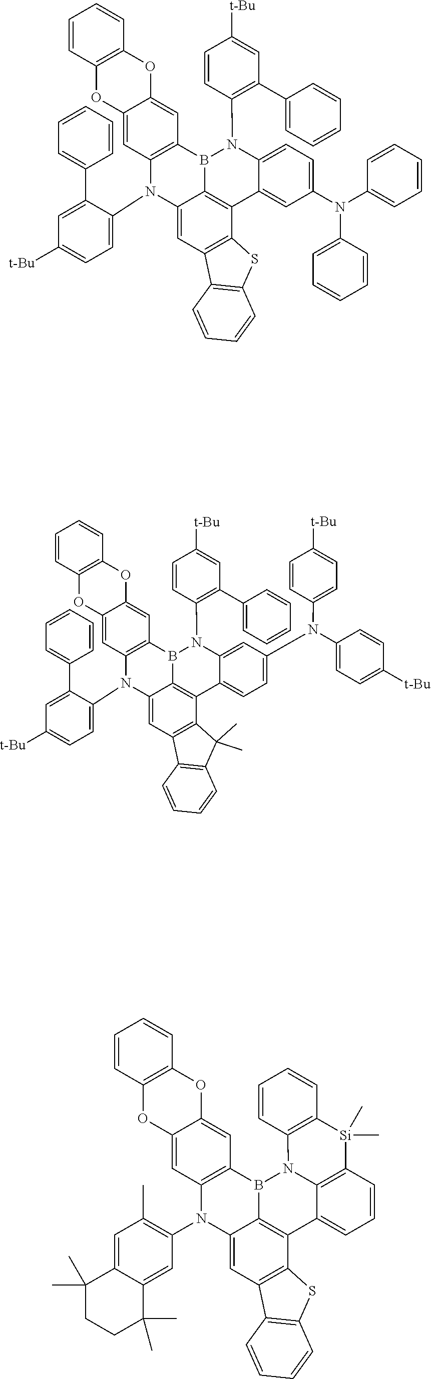 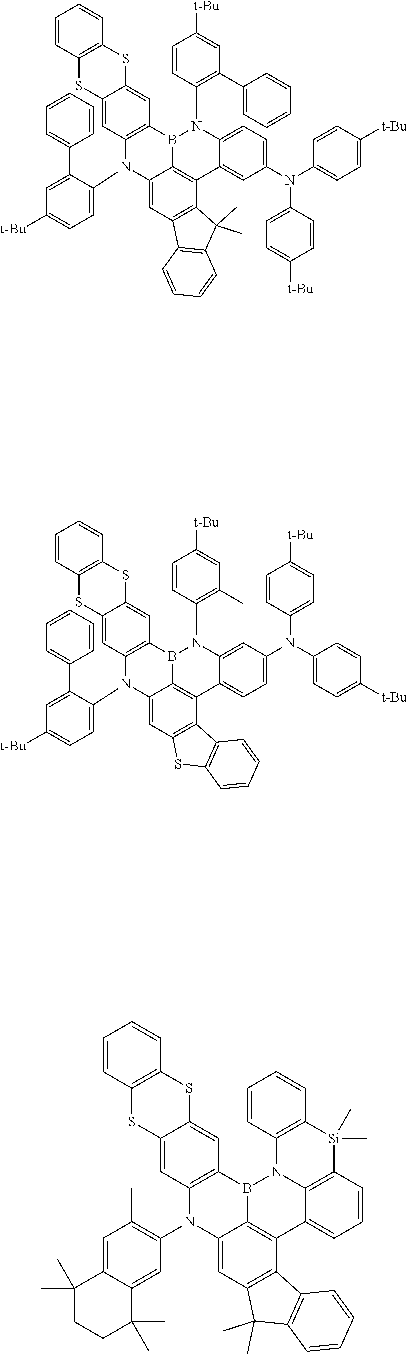 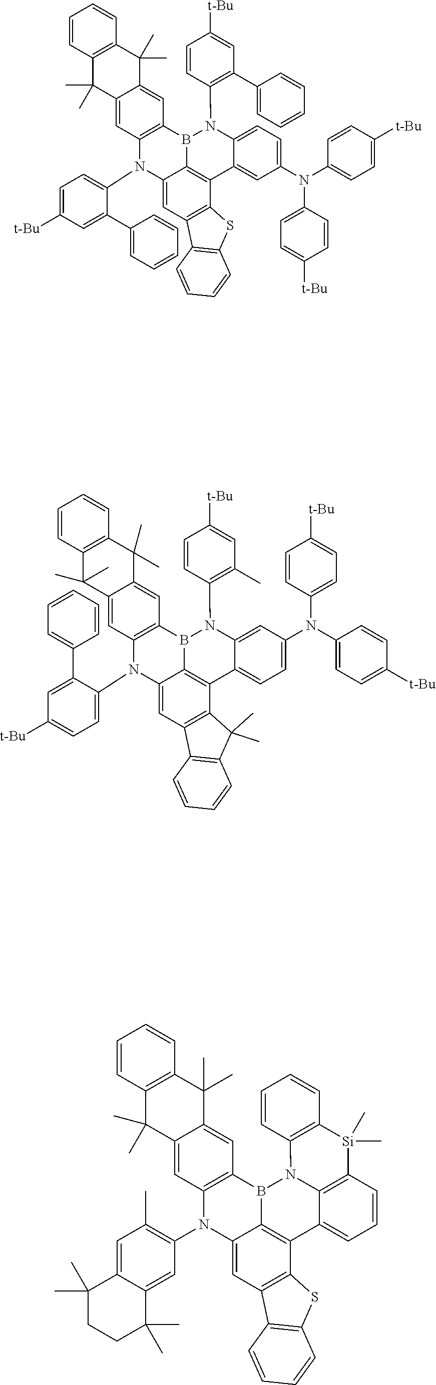 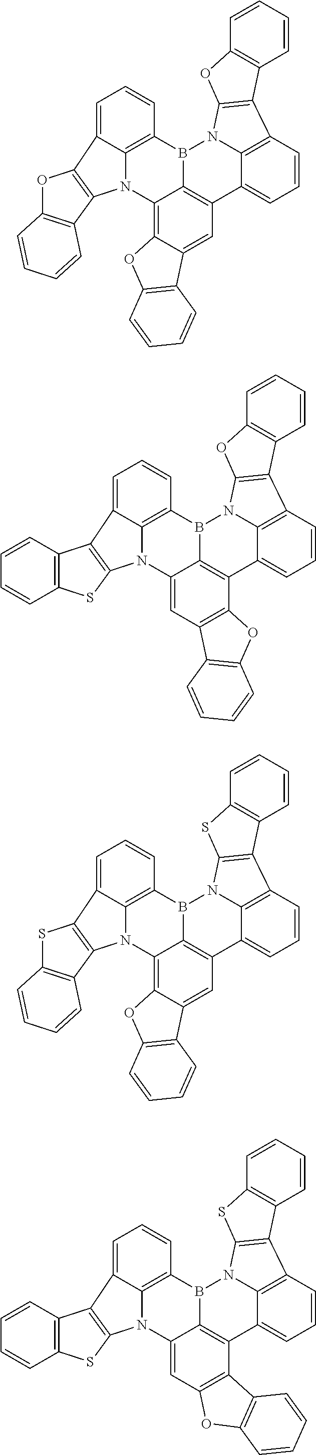 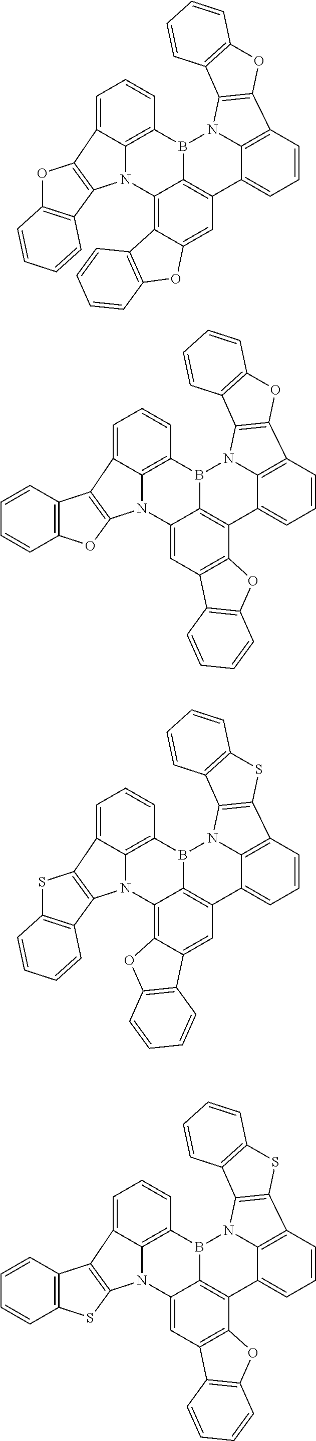 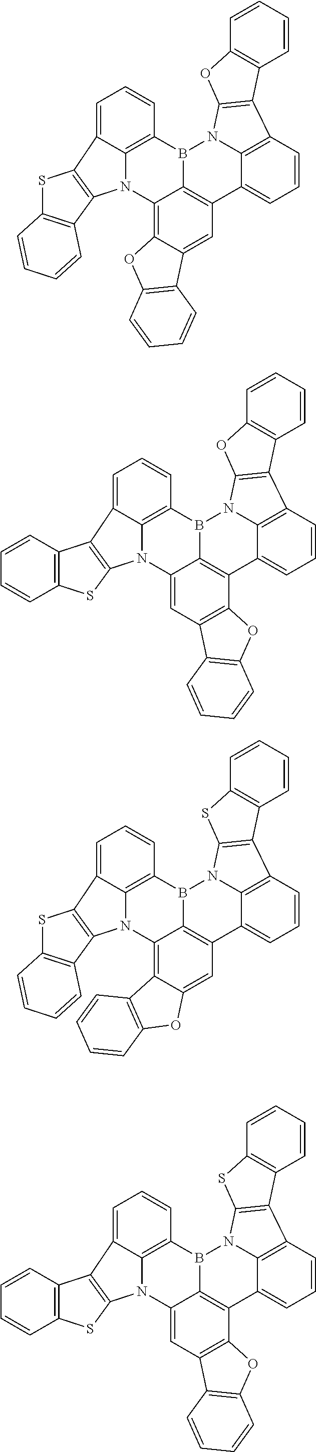 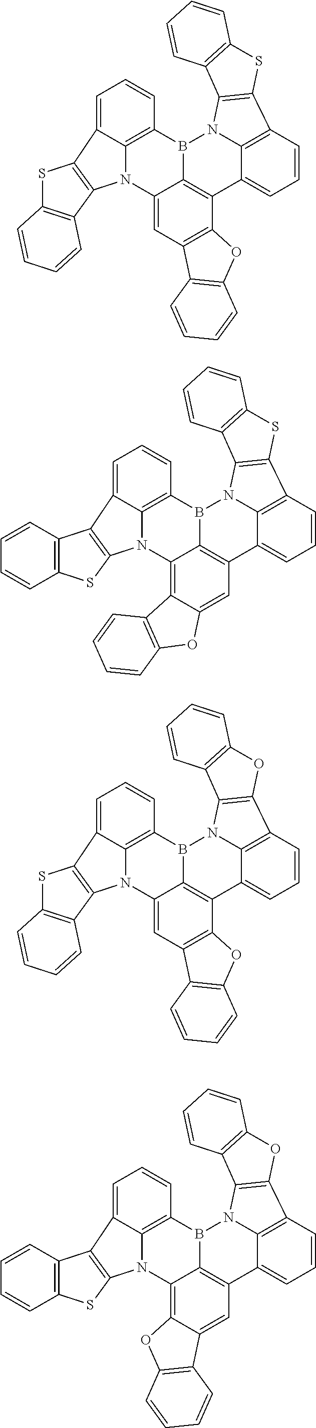 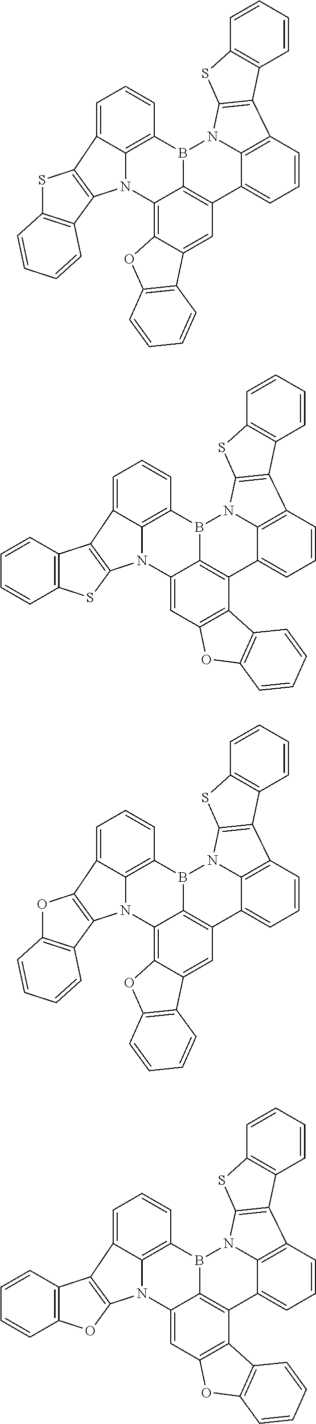 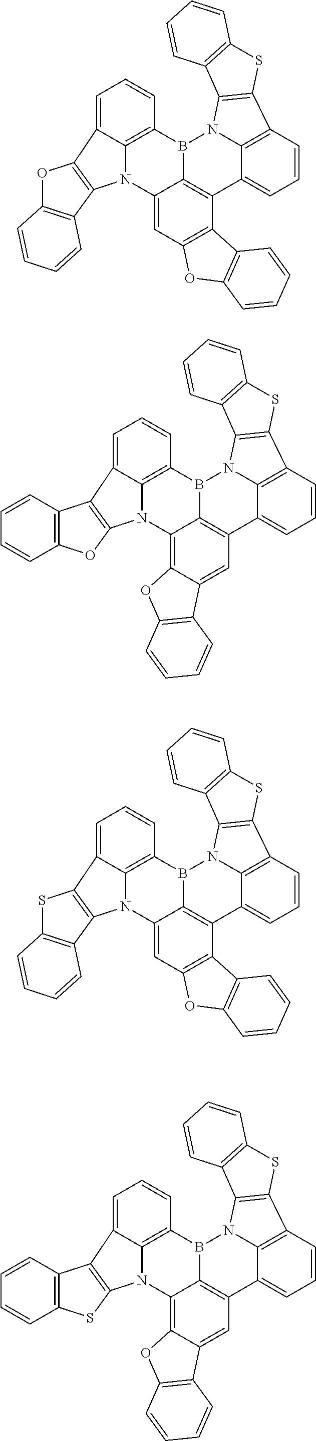 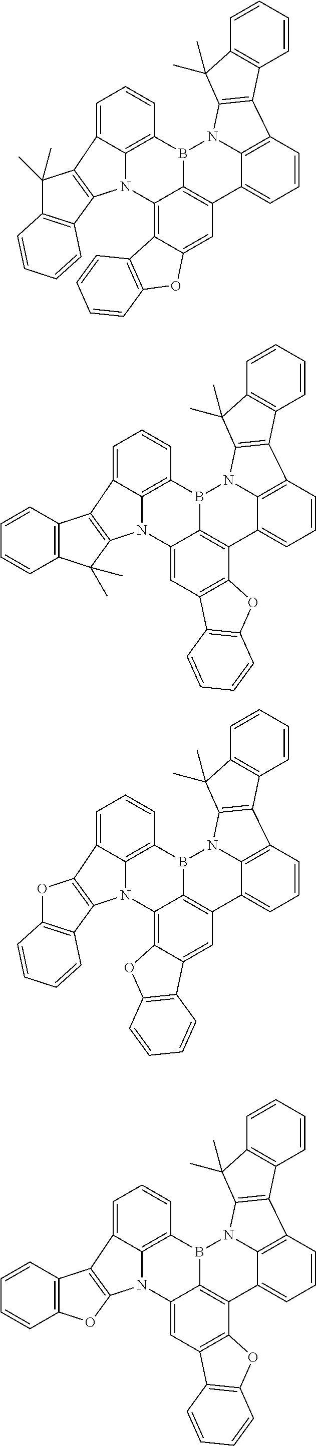 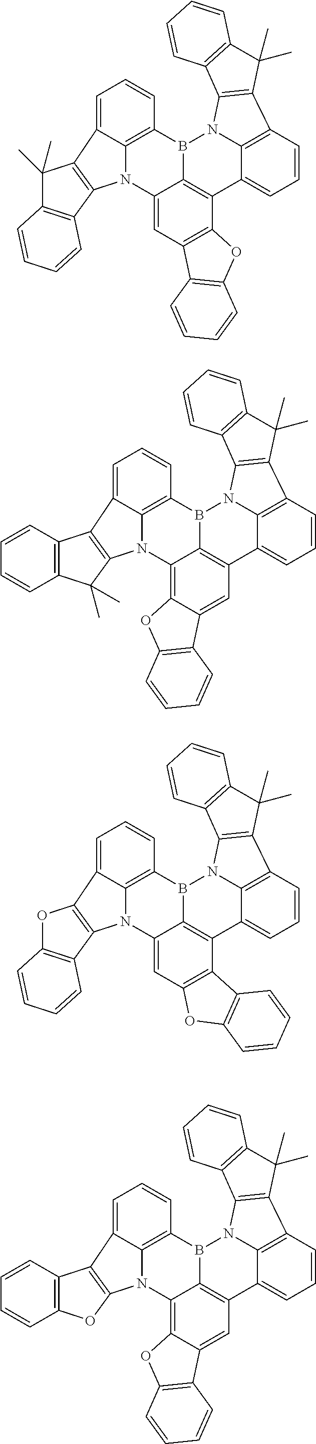 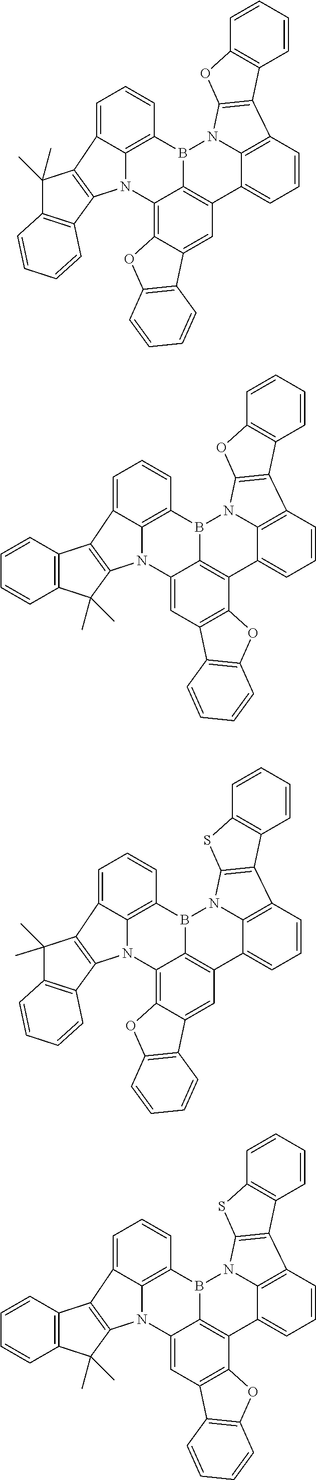 [SMILES: CC1(C)c2ccccc2-c2c1c1cccc3c1n2-c1c2c(cc4c1oc1ccccc14)-c1cccc4c5c6ccccc6oc5n(c14)B23 ; CC1(C)c2ccccc2-c2c1n1c3c(cccc23)B2c3c-1cc1c(oc4ccccc41)c3-c1cccc3c4c5ccccc5oc4n2c13 ; CC1(C)c2ccccc2-c2c1c1cccc3c1n2-c1c2c(cc4c1oc1ccccc14)-c1cccc4c5c6ccccc6sc5n(c14)B23 ; CC1(C)c2ccccc2-c2c1n1c3c(cccc23)B2c3c-1cc1c(oc4ccccc41)c3-c1cccc3c4c5ccccc5sc4n2c13] 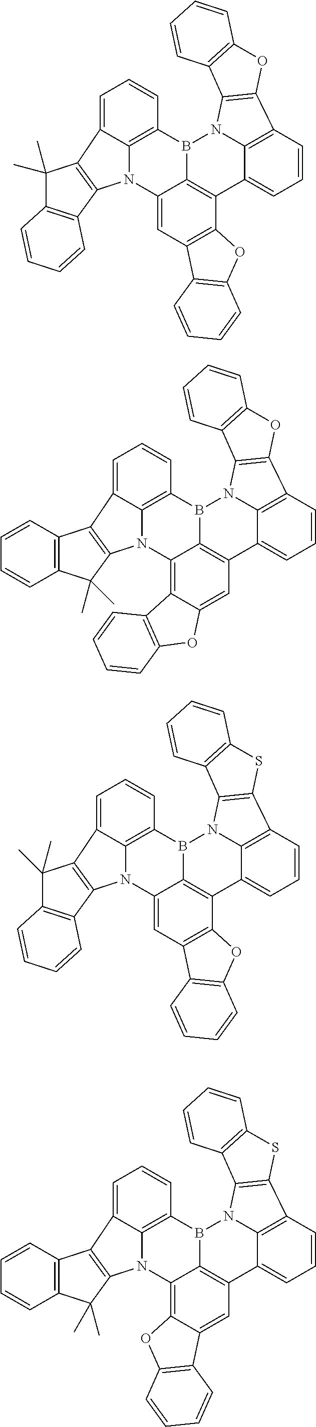 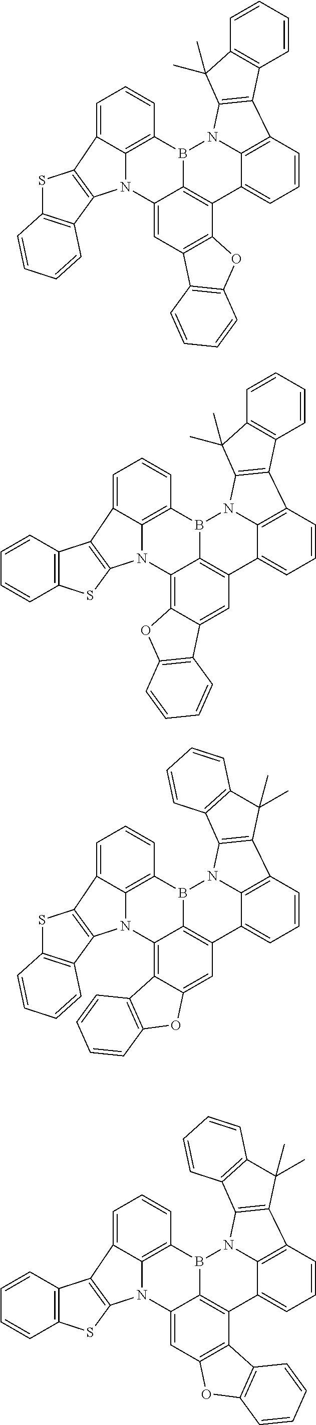 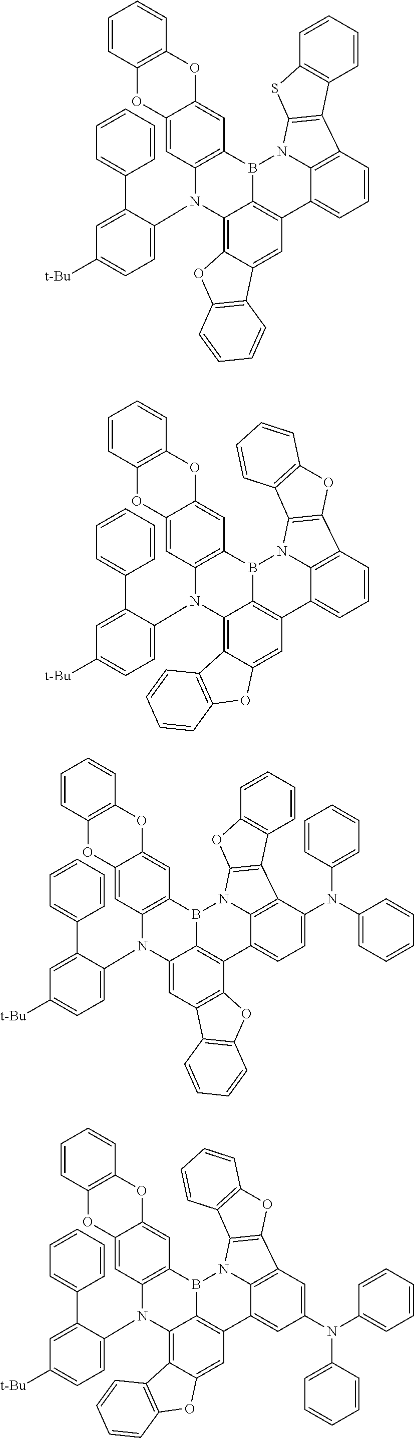 [SMILES: CC(C)(C)c1ccc(N2c3cc4c(cc3B3c5c(cc6c(oc7ccccc76)c52)-c2cccc5c6c7ccccc7sc6n3c25)Oc2ccccc2O4)c(-c2ccccc2)c1 ; CC(C)(C)c1ccc(N2c3cc4c(cc3B3c5c(cc6oc7ccccc7c6c52)-c2cccc5c6oc7ccccc7c6n3c25)Oc2ccccc2O4)c(-c2ccccc2)c1 ; CC(C)(C)c1ccc(N2c3cc4c(cc3B3c5c2cc2c(oc6ccccc62)c5-c2ccc(N(c5ccccc5)c5ccccc5)c5c6c7ccccc7oc6n3c25)Oc2ccccc2O4)c(-c2ccccc2)c1 ; CC(C)(C)c1ccc(N2c3cc4c(cc3B3c5c(cc6oc7ccccc7c6c52)-c2cc(N(c5ccccc5)c5ccccc5)cc5c6oc7ccccc7c6n3c25)Oc2ccccc2O4)c(-c2ccccc2)c1] 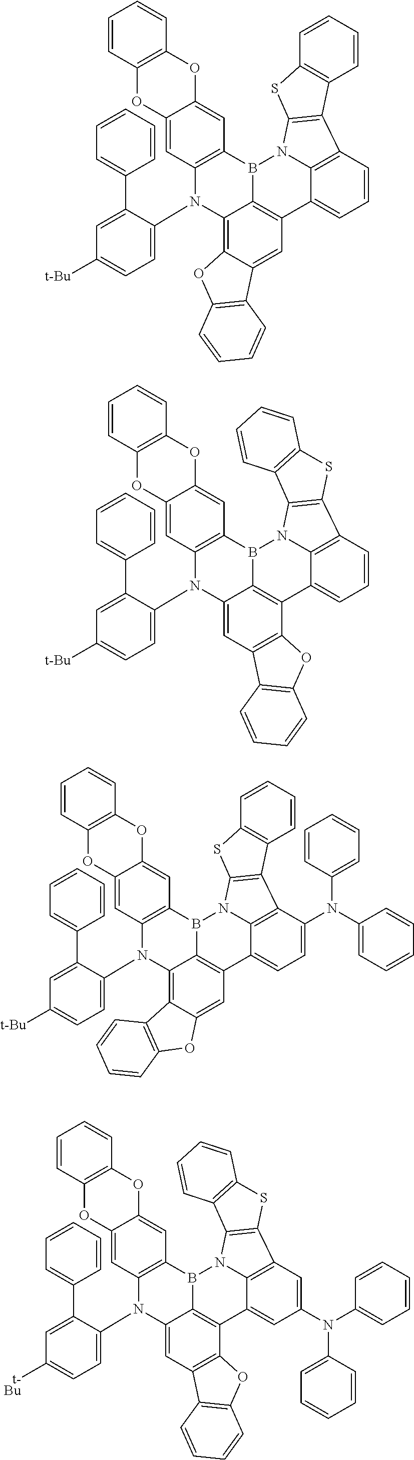 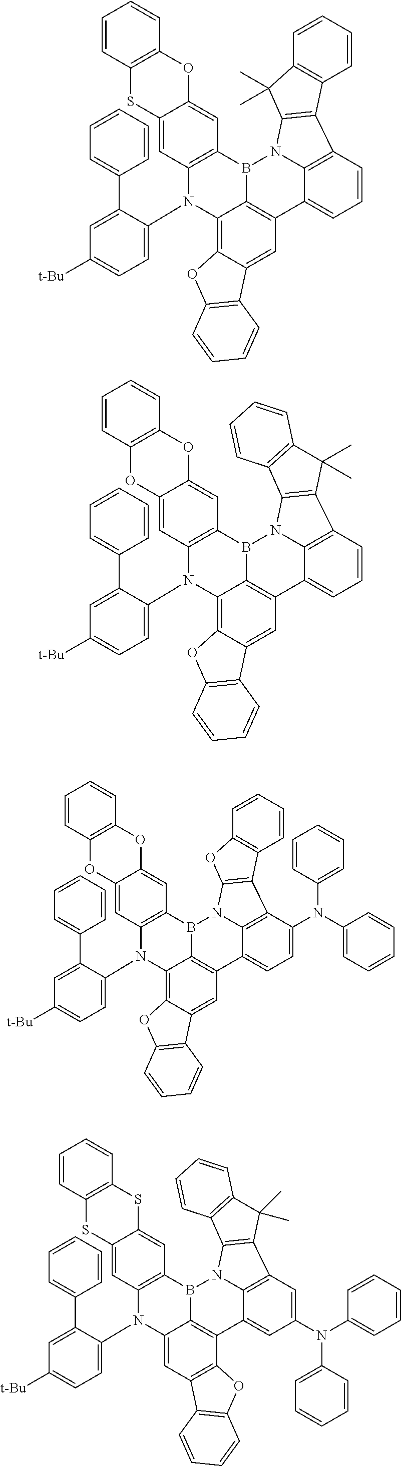 [SMILES: CC(C)(C)c1ccc(N2c3cc4c(cc3B3c5c(cc6c(oc7ccccc76)c52)-c2cccc5c6c(n3c25)C(C)(C)c2ccccc2-6)Oc2ccccc2S4)c(-c2ccccc2)c1 ; CC(C)(C)c1ccc(N2c3cc4c(cc3B3c5c(cc6c(oc7ccccc76)c52)-c2cccc5c6c(n3c25)-c2ccccc2C6(C)C)Oc2ccccc2O4)c(-c2ccccc2)c1 ; CC(C)(C)c1ccc(N2c3cc4c(cc3B3c5c(cc6c(oc7ccccc76)c52)-c2ccc(N(c5ccccc5)c5ccccc5)c5c6c7ccccc7oc6n3c25)Oc2ccccc2O4)c(-c2ccccc2)c1 ; CC(C)(C)c1ccc(N2c3cc4c(cc3B3c5c2cc2c(oc6ccccc62)c5-c2cc(N(c5ccccc5)c5ccccc5)cc5c6c(n3c25)-c2ccccc2C6(C)C)Sc2ccccc2S4)c(-c2ccccc2)c1] 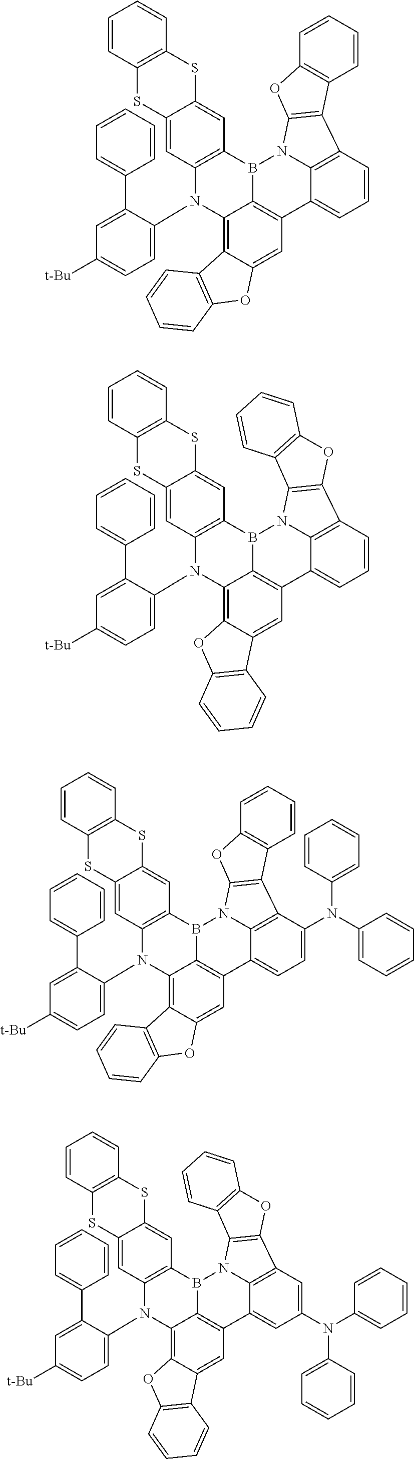 [SMILES: CC(C)(C)c1ccc(N2c3cc4c(cc3B3c5c(cc6oc7ccccc7c6c52)-c2cccc5c6c7ccccc7oc6n3c25)Sc2ccccc2S4)c(-c2ccccc2)c1 ; CC(C)(C)c1ccc(N2c3cc4c(cc3B3c5c(cc6c(oc7ccccc76)c52)-c2cccc5c6oc7ccccc7c6n3c25)Sc2ccccc2S4)c(-c2ccccc2)c1 ; CC(C)(C)c1ccc(N2c3cc4c(cc3B3c5c(cc6oc7ccccc7c6c52)-c2ccc(N(c5ccccc5)c5ccccc5)c5c6c7ccccc7oc6n3c25)Sc2ccccc2S4)c(-c2ccccc2)c1 ; CC(C)(C)c1ccc(N2c3cc4c(cc3B3c5c(cc6c(oc7ccccc76)c52)-c2cc(N(c5ccccc5)c5ccccc5)cc5c6oc7ccccc7c6n3c25)Sc2ccccc2S4)c(-c2ccccc2)c1] 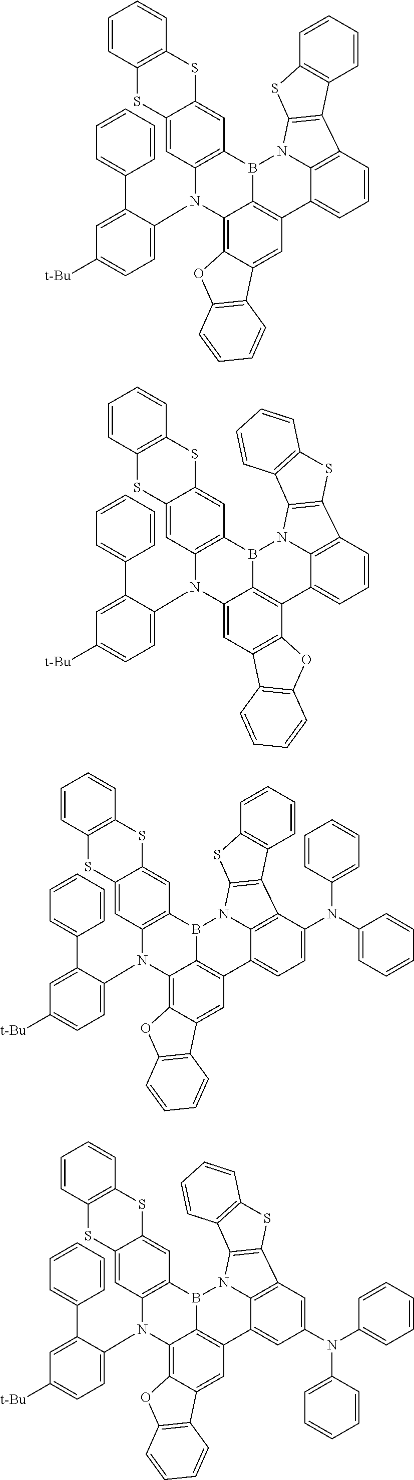 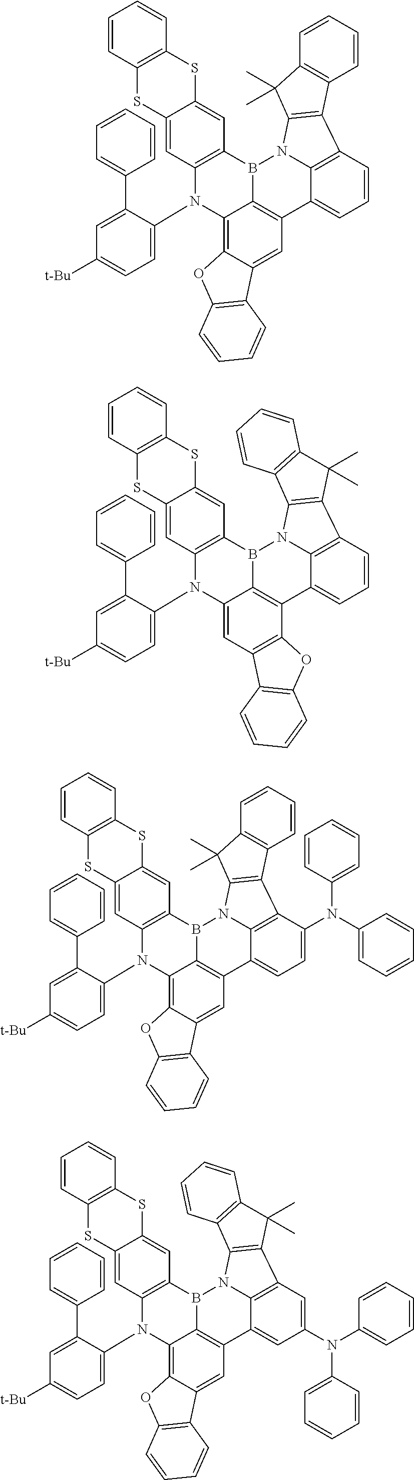 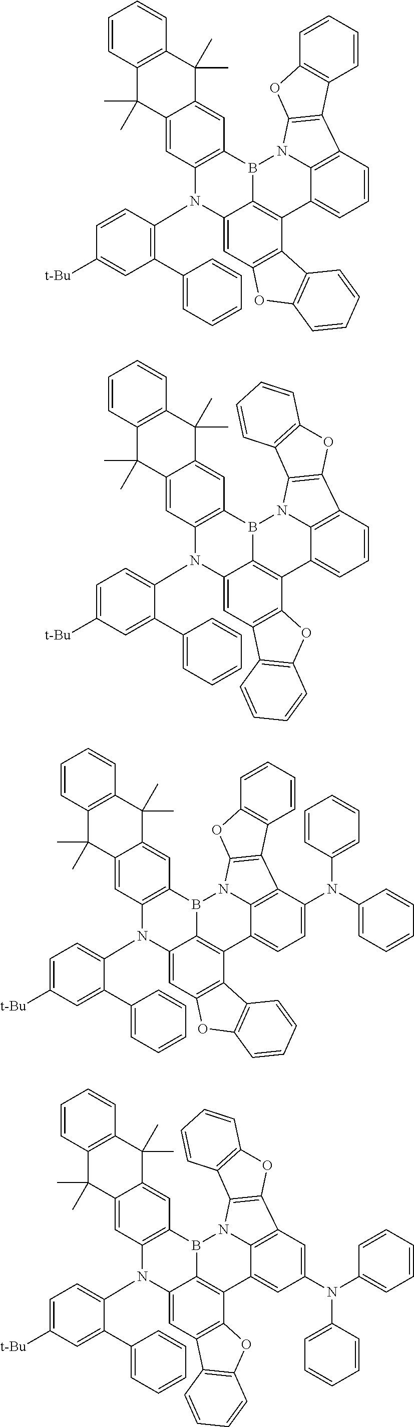 [SMILES: CC(C)(C)c1ccc(N2c3cc4c(cc3B3c5c2cc2oc6ccccc6c2c5-c2cccc5c6c7ccccc7oc6n3c25)C(C)(C)c2ccccc2C4(C)C)c(-c2ccccc2)c1 ; CC(C)(C)c1ccc(N2c3cc4c(cc3B3c5c2cc2c(oc6ccccc62)c5-c2cccc5c6oc7ccccc7c6n3c25)C(C)(C)c2ccccc2C4(C)C)c(-c2ccccc2)c1 ; CC(C)(C)c1ccc(N2c3cc4c(cc3B3c5c2cc2oc6ccccc6c2c5-c2ccc(N(c5ccccc5)c5ccccc5)c5c6c7ccccc7oc6n3c25)C(C)(C)c2ccccc2C4(C)C)c(-c2ccccc2)c1 ; CC(C)(C)c1ccc(N2c3cc4c(cc3B3c5c2cc2c(oc6ccccc62)c5-c2cc(N(c5ccccc5)c5ccccc5)cc5c6oc7ccccc7c6n3c25)C(C)(C)c2ccccc2C4(C)C)c(-c2ccccc2)c1] 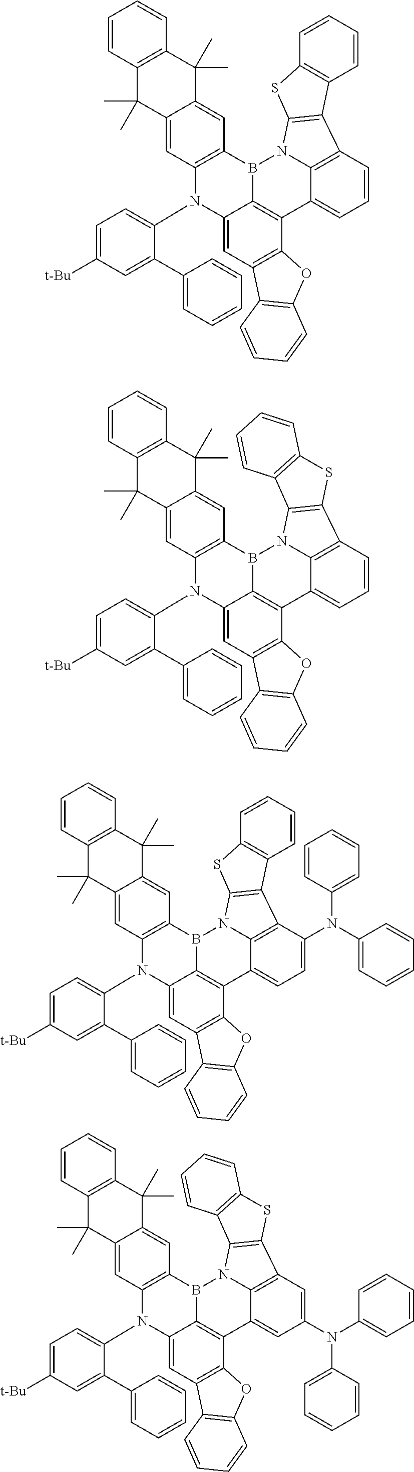 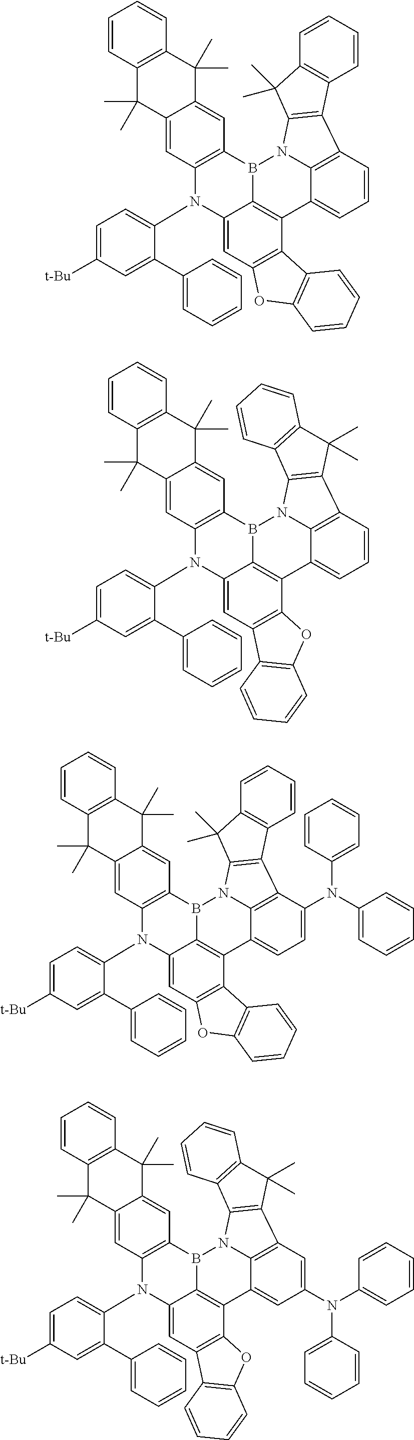 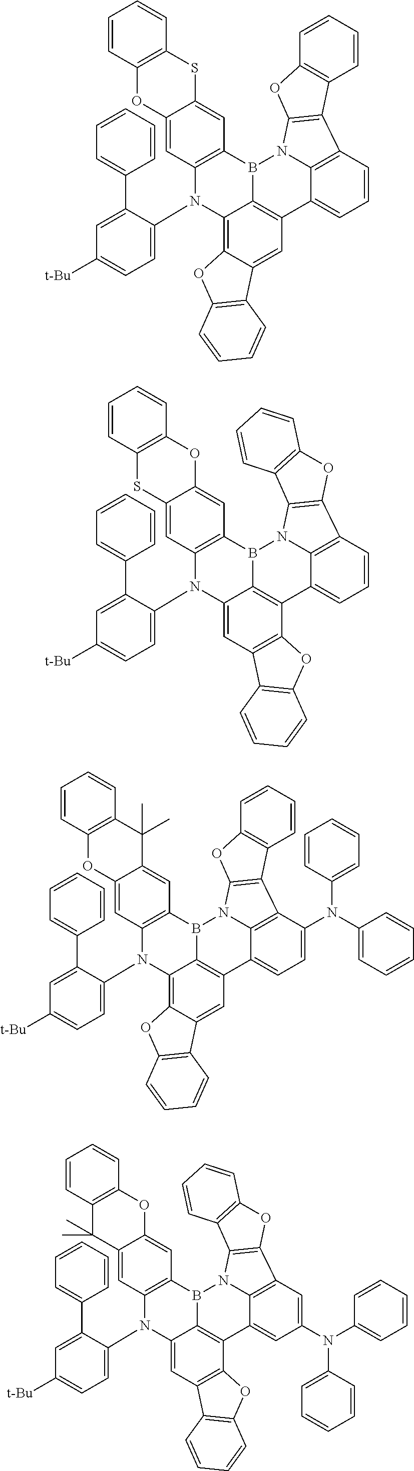 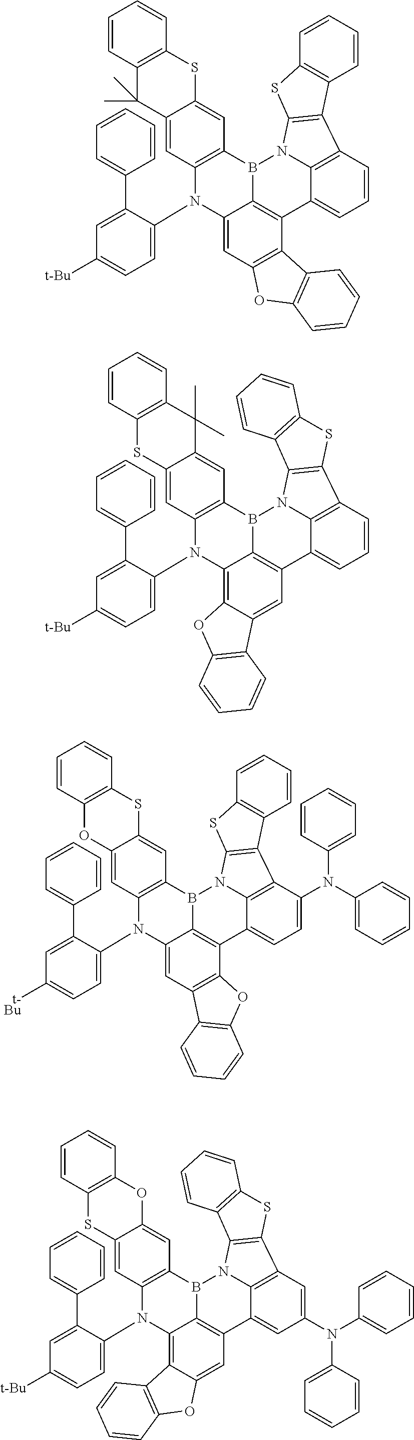 [SMILES: CC(C)(C)c1ccc(N2c3cc4c(cc3B3c5c2cc2oc6ccccc6c2c5-c2cccc5c6c7ccccc7sc6n3c25)Sc2ccccc2C4(C)C)c(-c2ccccc2)c1 ; CC(C)(C)c1ccc(N2c3cc4c(cc3B3c5c(cc6c(oc7ccccc76)c52)-c2cccc5c6sc7ccccc7c6n3c25)C(C)(C)c2ccccc2S4)c(-c2ccccc2)c1 ; CC(C)(C)c1ccc(N2c3cc4c(cc3B3c5c2cc2c(oc6ccccc62)c5-c2ccc(N(c5ccccc5)c5ccccc5)c5c6c7ccccc7sc6n3c25)Sc2ccccc2O4)c(-c2ccccc2)c1 ; CC(C)(C)c1ccc(N2c3cc4c(cc3B3c5c(cc6oc7ccccc7c6c52)-c2cc(N(c5ccccc5)c5ccccc5)cc5c6sc7ccccc7c6n3c25)Oc2ccccc2S4)c(-c2ccccc2)c1] 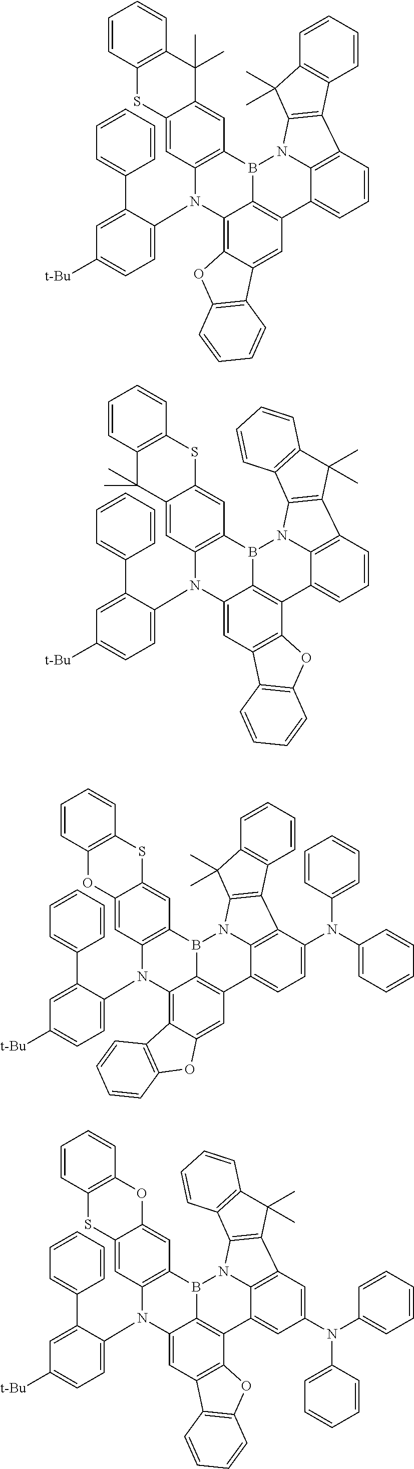 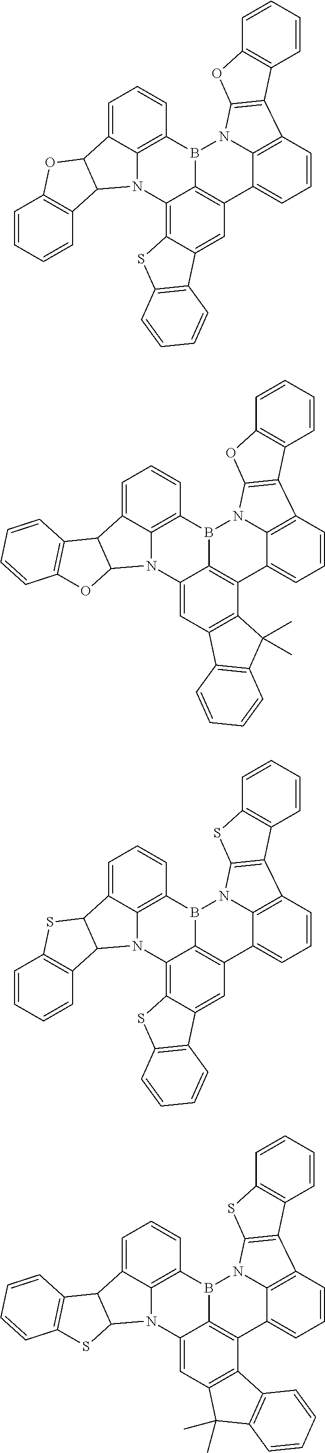 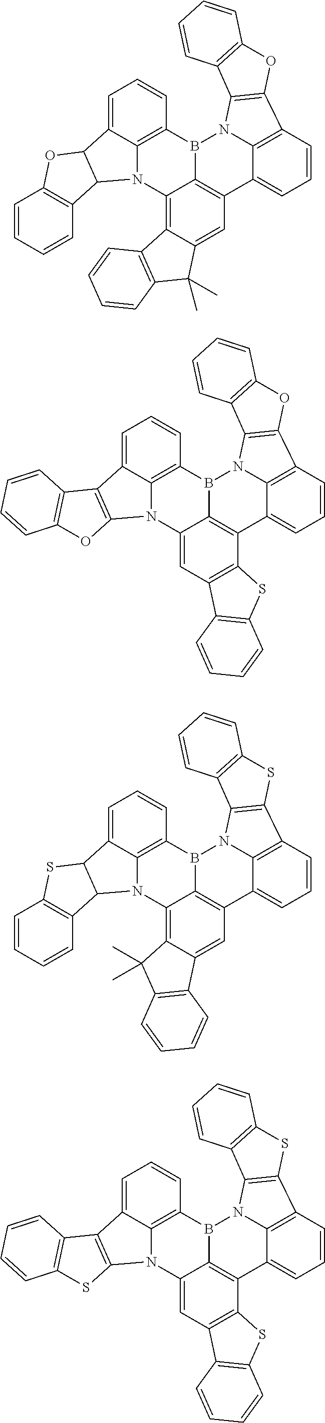 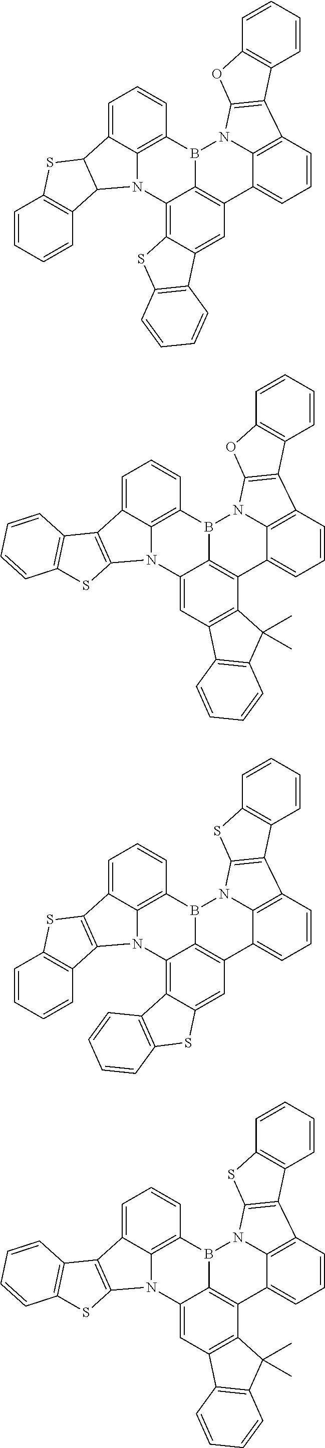 [SMILES: c1ccc2c(c1)SC1c3cccc4c3N(c3c5c(cc6c3sc3ccccc36)-c3cccc6c7c8ccccc8oc7n(c36)B45)C21 ; CC1(C)c2ccccc2-c2cc3c4c(c21)-c1cccc2c5c6ccccc6oc5n(c12)B4c1cccc2c4c5ccccc5sc4n-3c12 ; c1ccc2c(c1)sc1cc3c4c(c12)-n1c2c(cccc2c2sc5ccccc5c21)B4n1c2sc4ccccc4c2c2cccc-3c21 ; CC1(C)c2ccccc2-c2cc3c4c(c21)-c1cccc2c5c6ccccc6sc5n(c12)B4c1cccc2c4c5ccccc5sc4n-3c12] 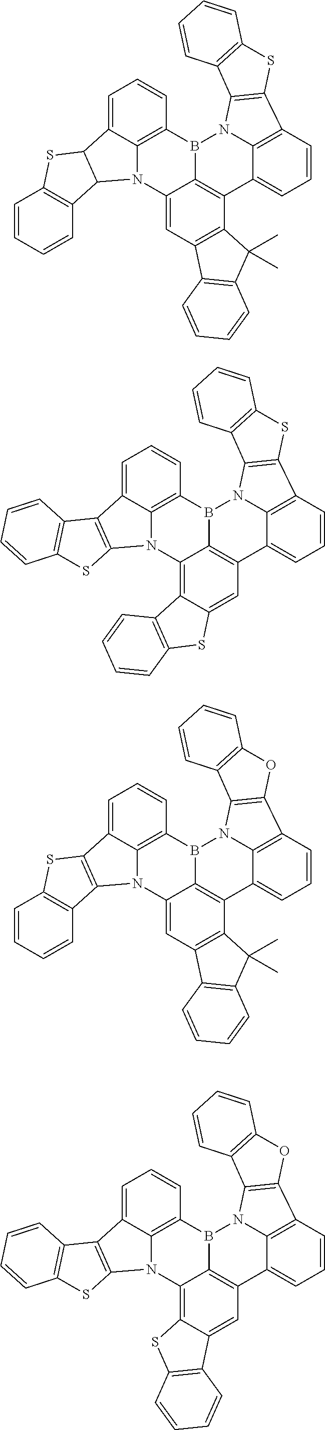 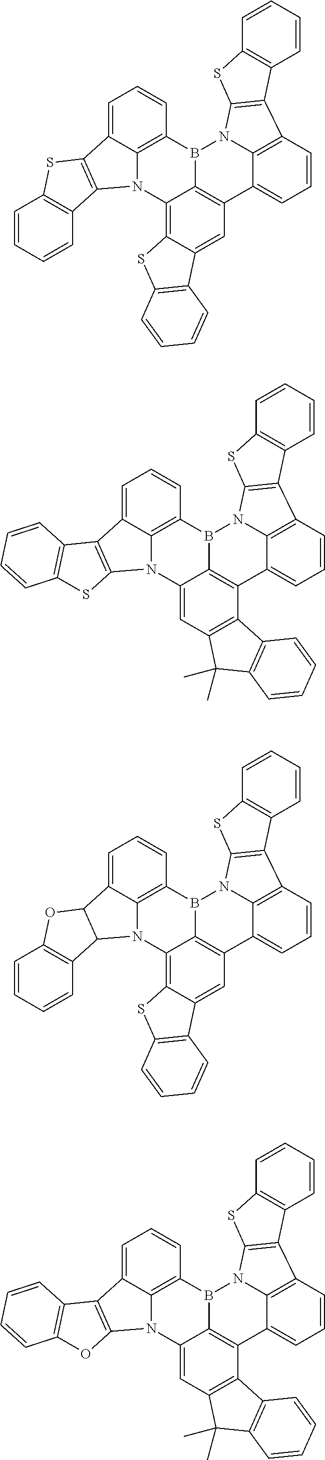 [SMILES: c1ccc2c(c1)sc1c3c4c(cc12)-c1cccc2c5c6ccccc6sc5n(c12)B4c1cccc2c4sc5ccccc5c4n-3c12 ; CC1(C)c2ccccc2-c2c1cc1c3c2-c2cccc4c5c6ccccc6sc5n(c24)B3c2cccc3c4c5ccccc5sc4n-1c23 ; c1ccc2c(c1)OC1c3cccc4c3N(c3c5c(cc6c3sc3ccccc36)-c3cccc6c7c8ccccc8sc7n(c36)B45)C21 ; CC1(C)c2ccccc2-c2c1cc1c3c2-c2cccc4c5c6ccccc6sc5n(c24)B3c2cccc3c4c5ccccc5oc4n-1c23] 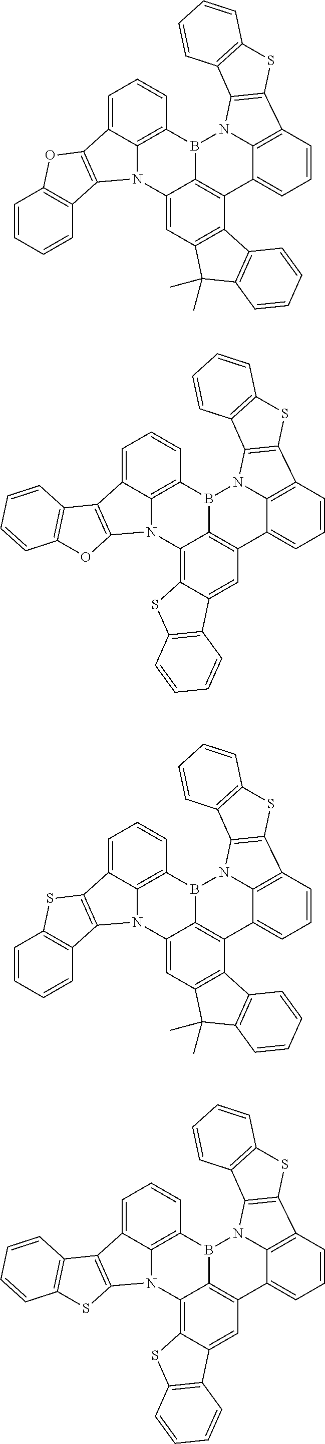 [SMILES: CC1(C)c2ccccc2-c2c1cc1c3c2-c2cccc4c5sc6ccccc6c5n(c24)B3c2cccc3c4oc5ccccc5c4n-1c23 ; c1ccc2c(c1)oc1c2c2cccc3c2n1-c1c2c(cc4c1sc1ccccc14)-c1cccc4c5sc6ccccc6c5n(c14)B23 ; CC1(C)c2ccccc2-c2c1cc1c3c2-c2cccc4c5sc6ccccc6c5n(c24)B3c2cccc3c4sc5ccccc5c4n-1c23 ; c1ccc2c(c1)sc1c3c4c(cc12)-c1cccc2c5sc6ccccc6c5n(c12)B4c1cccc2c4c5ccccc5sc4n-3c12] 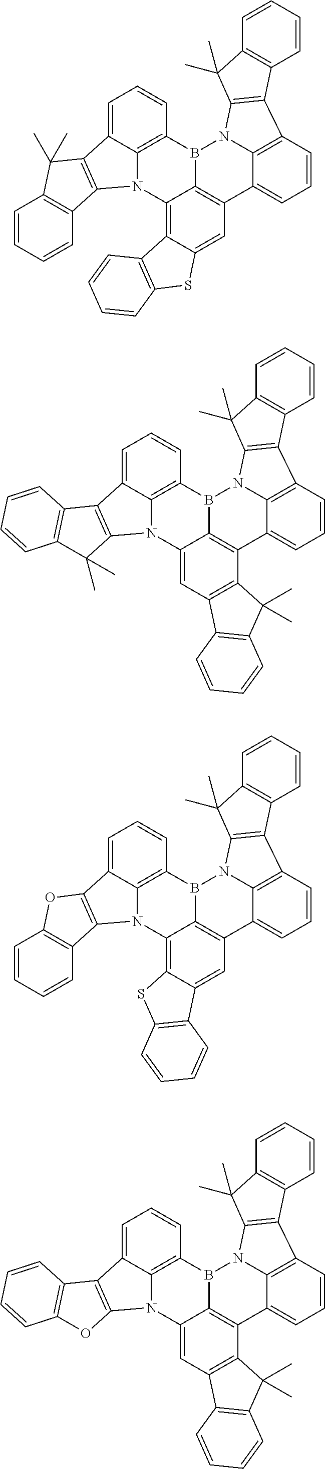 [SMILES: CC1(C)c2ccccc2-c2c1c1cccc3c1n2-c1c2c(cc4sc5ccccc5c14)-c1cccc4c5c(n(c14)B23)C(C)(C)c1ccccc1-5 ; CC1(C)c2ccccc2-c2cc3c4c(c21)-c1cccc2c5c(n(c12)B4c1cccc2c4c(n-3c12)C(C)(C)c1ccccc1-4)C(C)(C)c1ccccc1-5 ; CC1(C)c2ccccc2-c2c1n1c3c(cccc23)-c2cc3c(sc4ccccc43)c3c2B1c1cccc2c4oc5ccccc5c4n-3c12 ; CC1(C)c2ccccc2-c2cc3c4c(c21)-c1cccc2c5c(n(c12)B4c1cccc2c4c6ccccc6oc4n-3c12)C(C)(C)c1ccccc1-5] 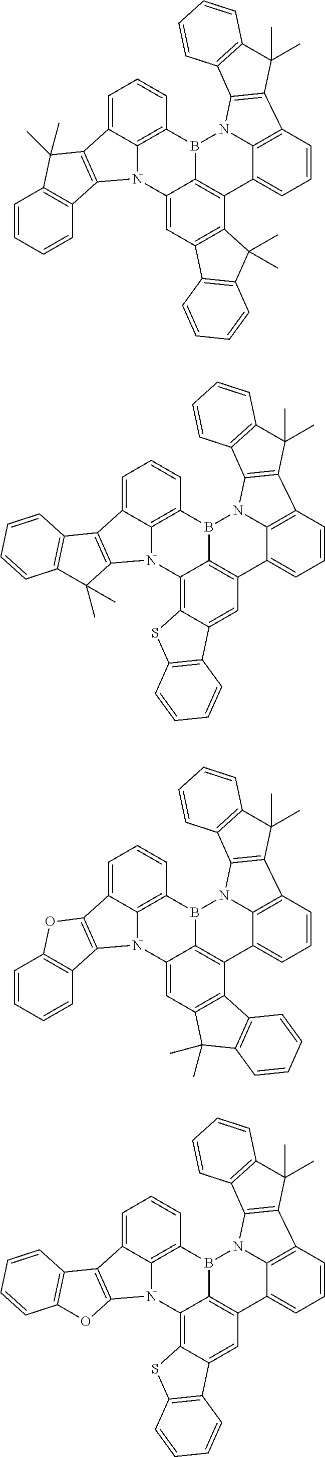 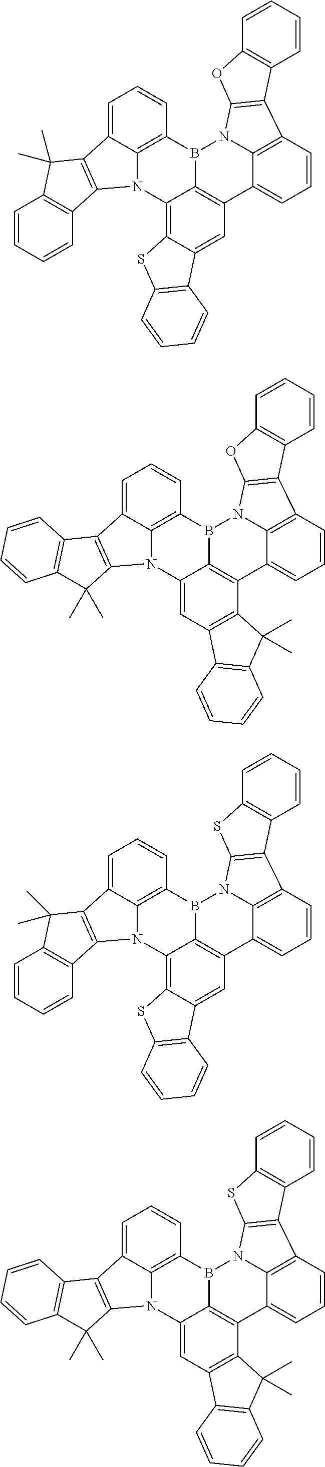 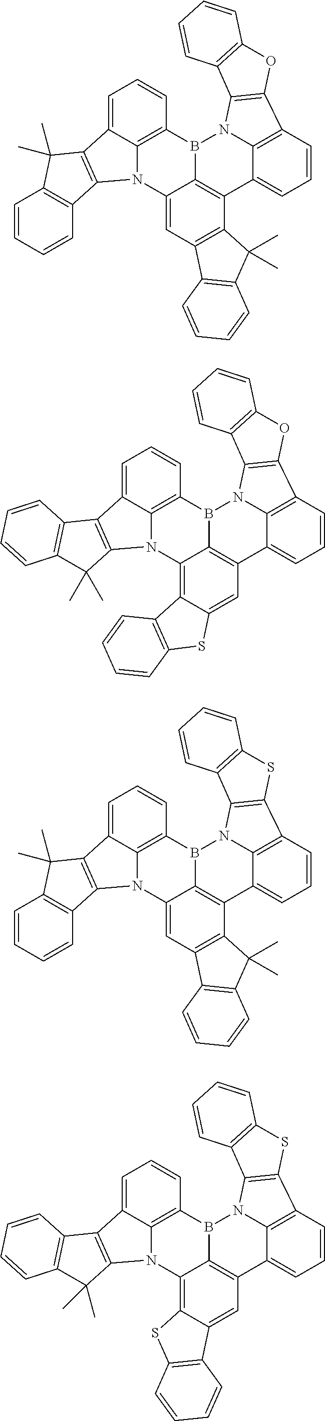 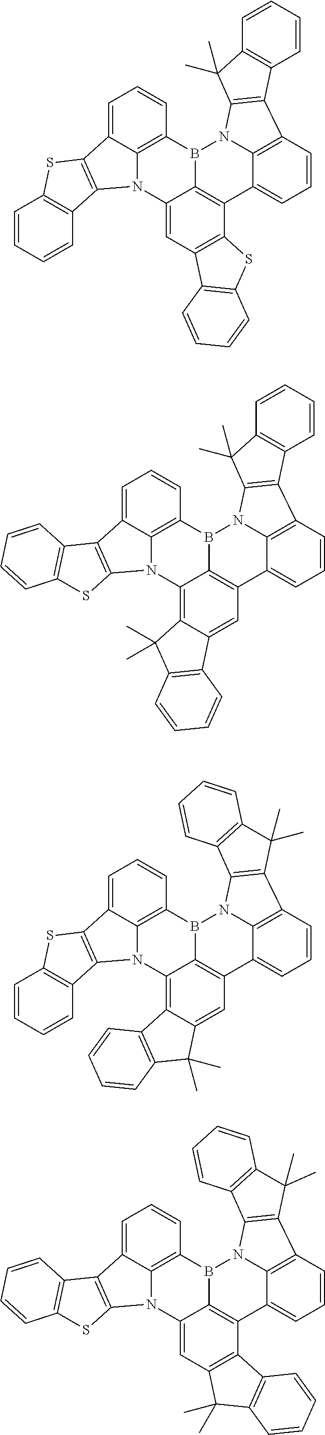 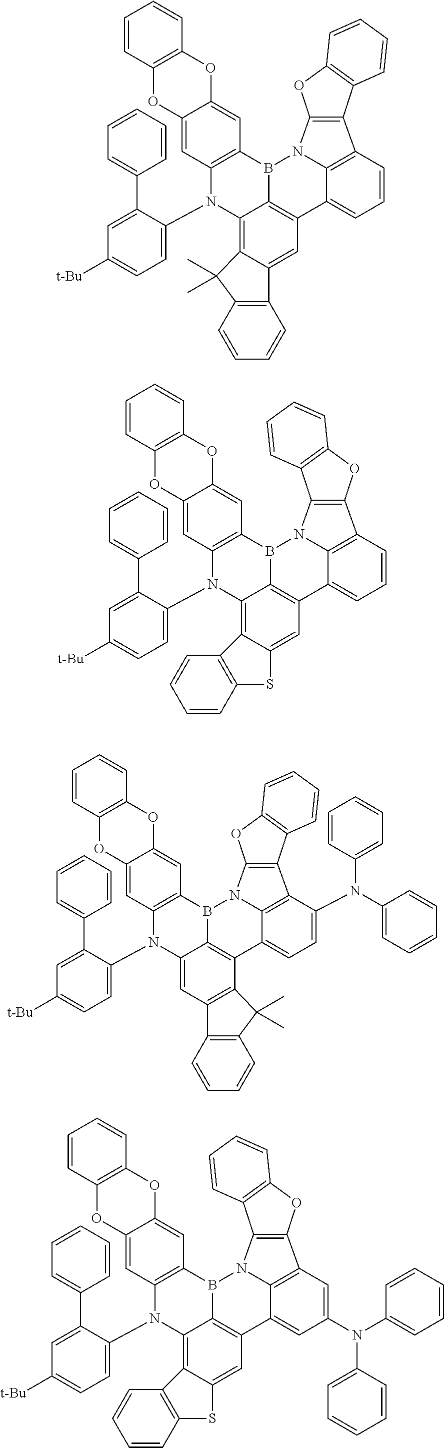 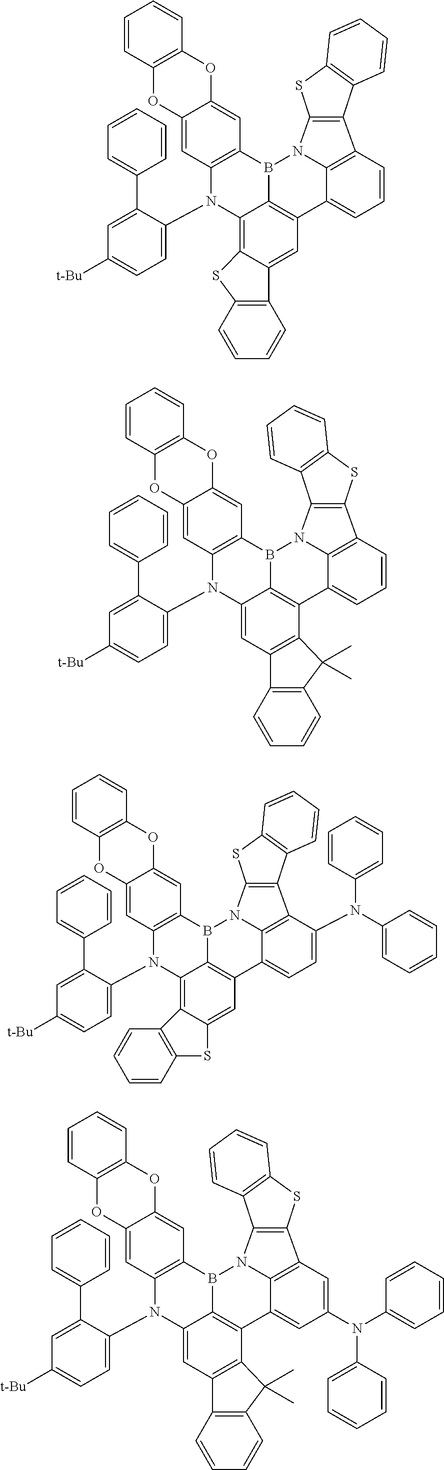 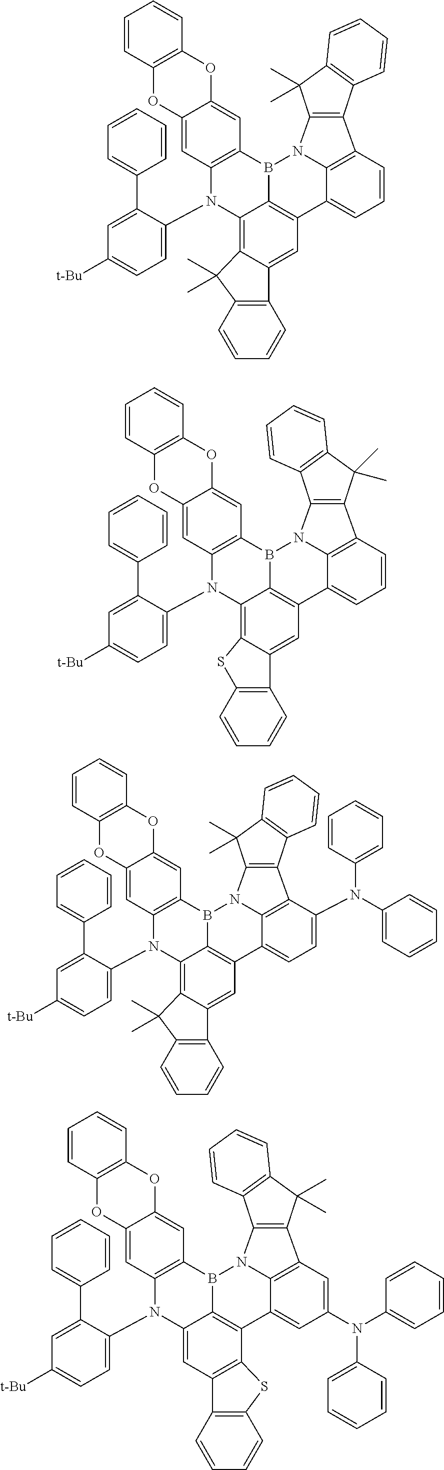 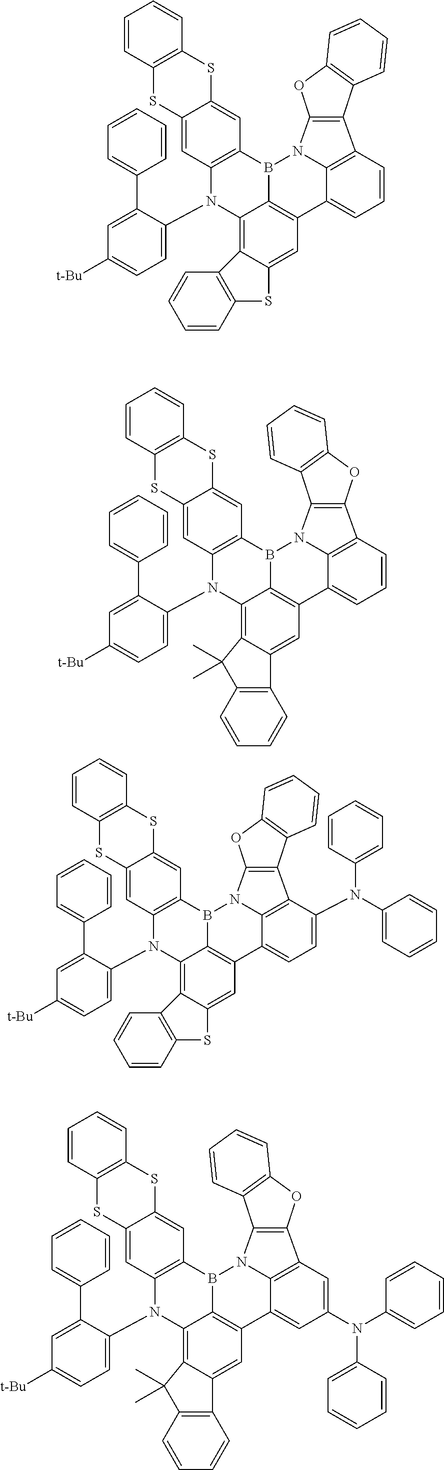 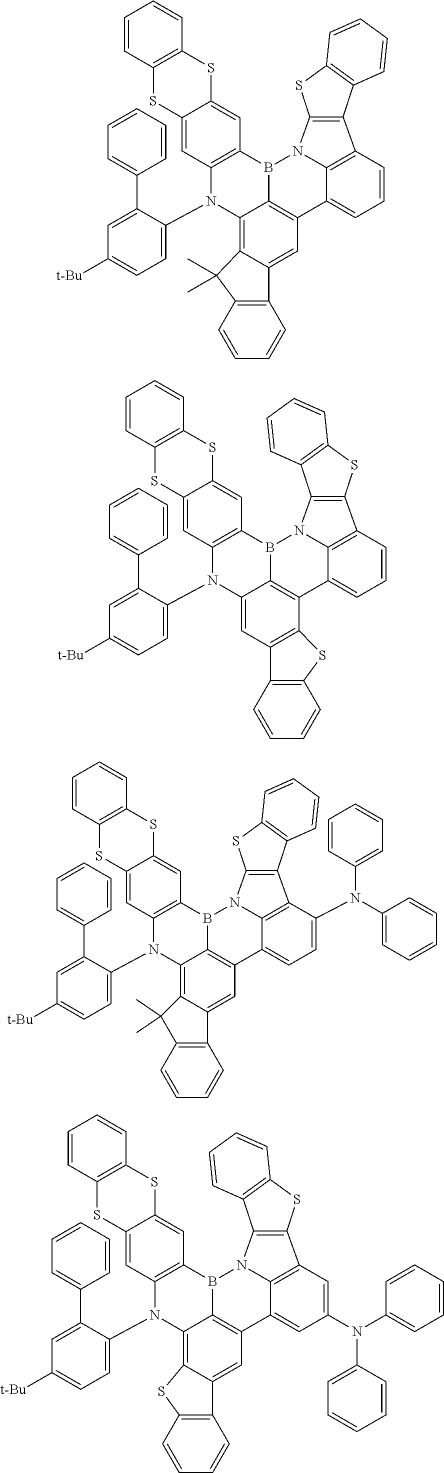 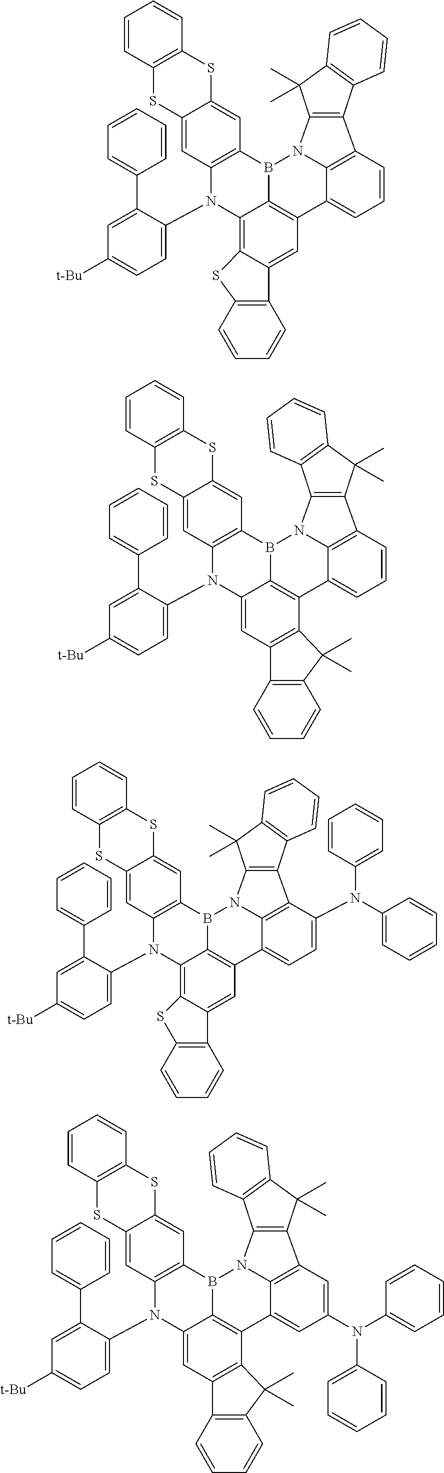 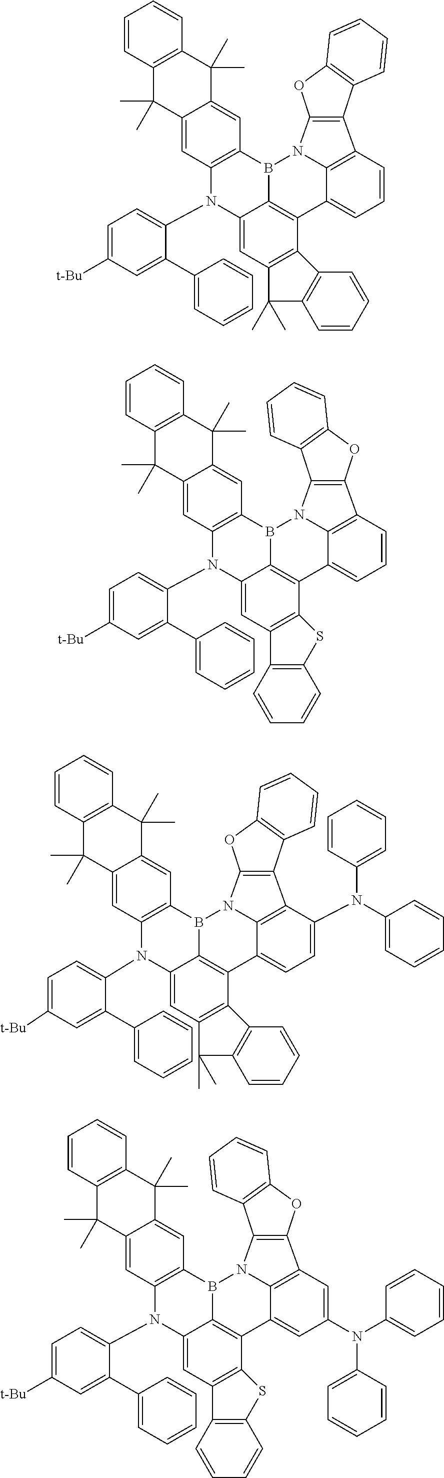 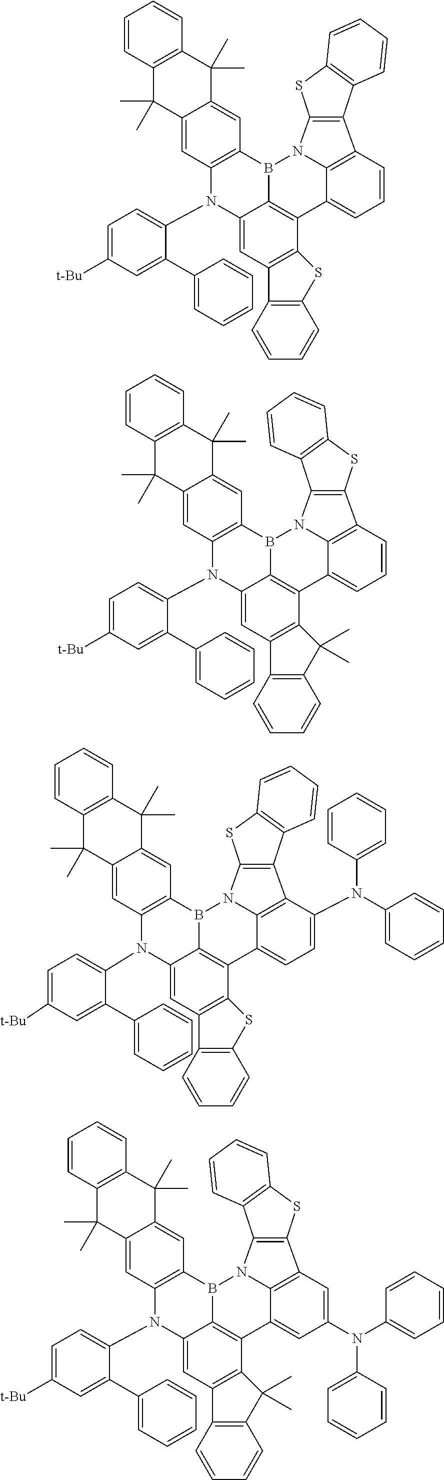 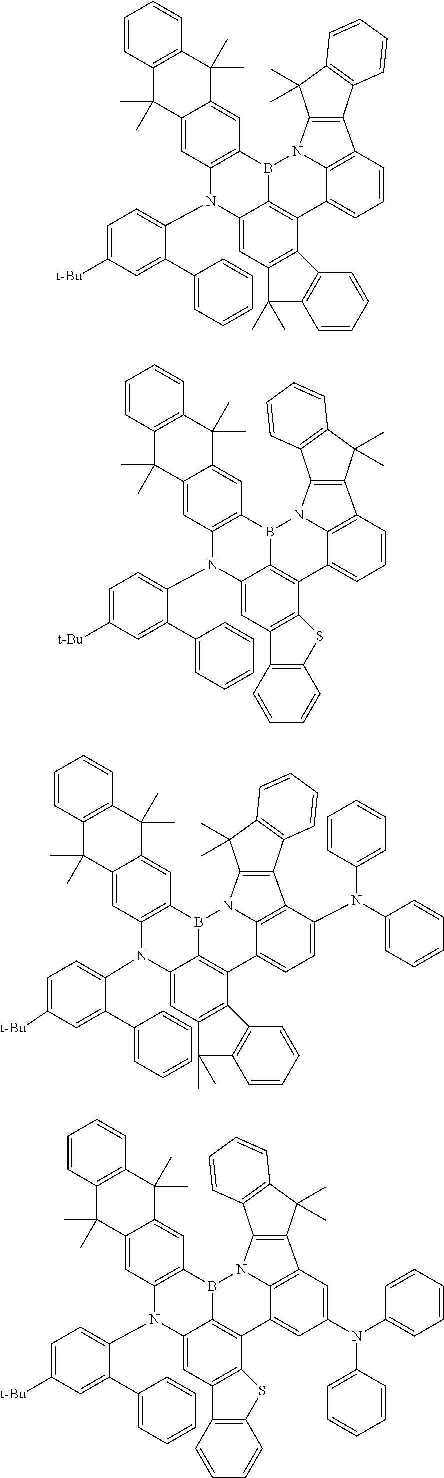 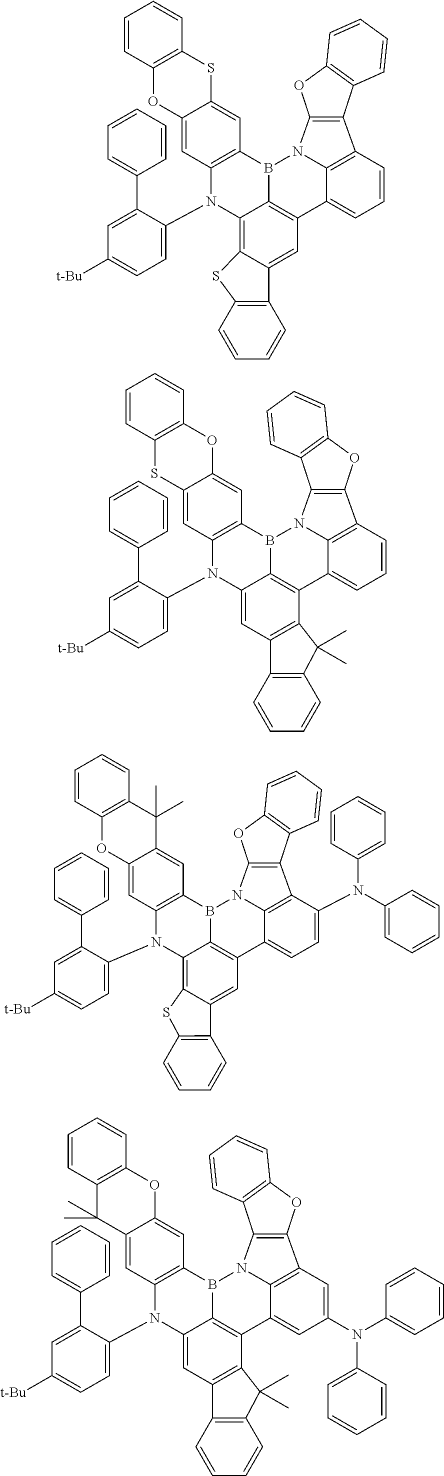 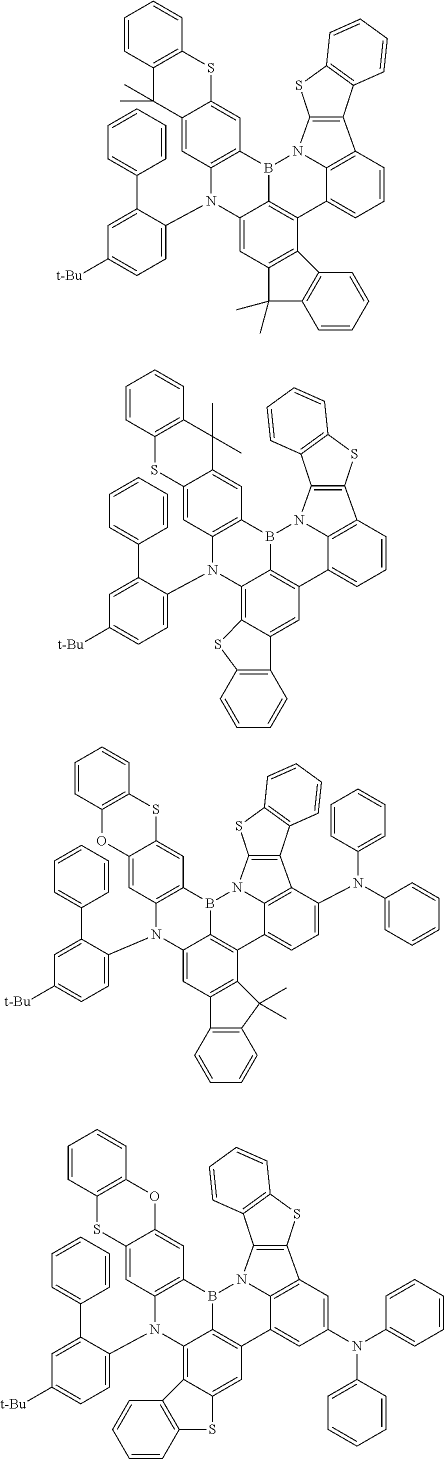 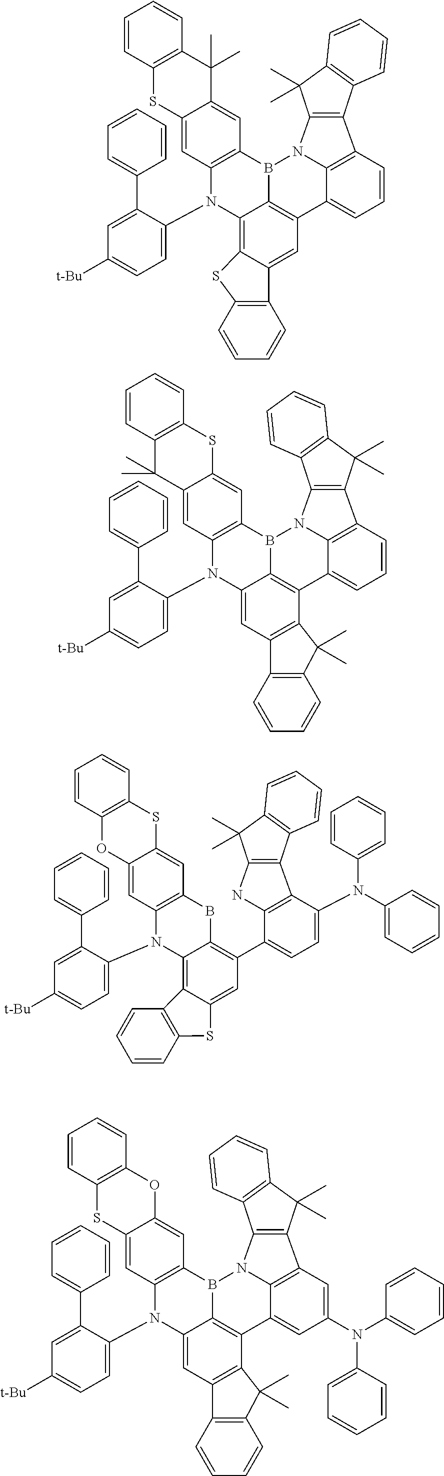 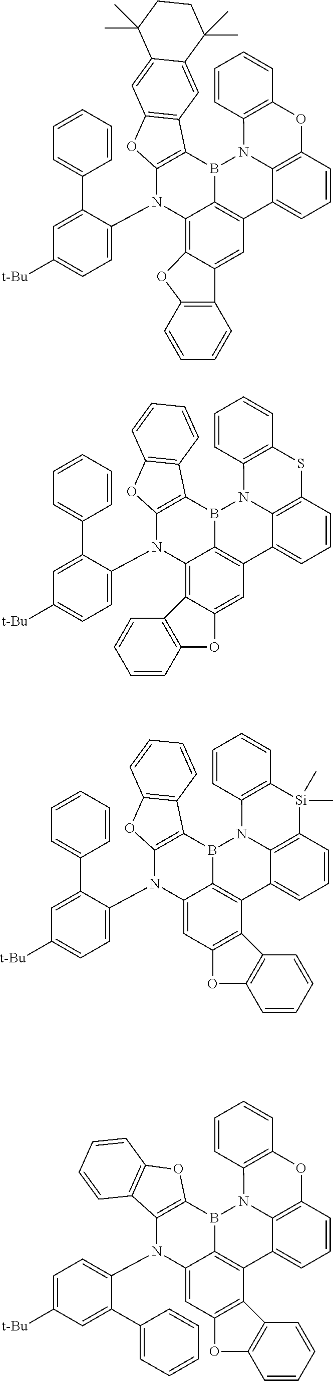 [SMILES: CC(C)(C)c1ccc(N2c3oc4cc5c(cc4c3B3c4c(cc6c(oc7ccccc76)c42)-c2cccc4c2N3c2ccccc2O4)C(C)(C)CCC5(C)C)c(-c2ccccc2)c1 ; CC(C)(C)c1ccc(N2c3oc4ccccc4c3B3c4c(cc5oc6ccccc6c5c42)-c2cccc4c2N3c2ccccc2S4)c(-c2ccccc2)c1 ; CC(C)(C)c1ccc(N2c3cc4oc5ccccc5c4c4c3B(c3c2oc2ccccc32)N2c3ccccc3[Si](C)(C)c3cccc-4c32)c(-c2ccccc2)c1 ; CC(C)(C)c1ccc(N2c3cc4oc5ccccc5c4c4c3B(c3oc5ccccc5c32)N2c3ccccc3Oc3cccc-4c32)c(-c2ccccc2)c1] 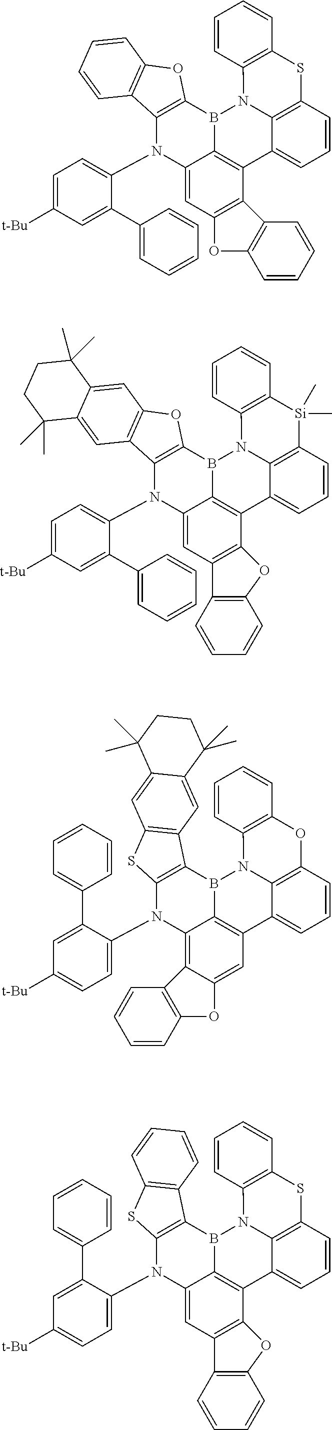 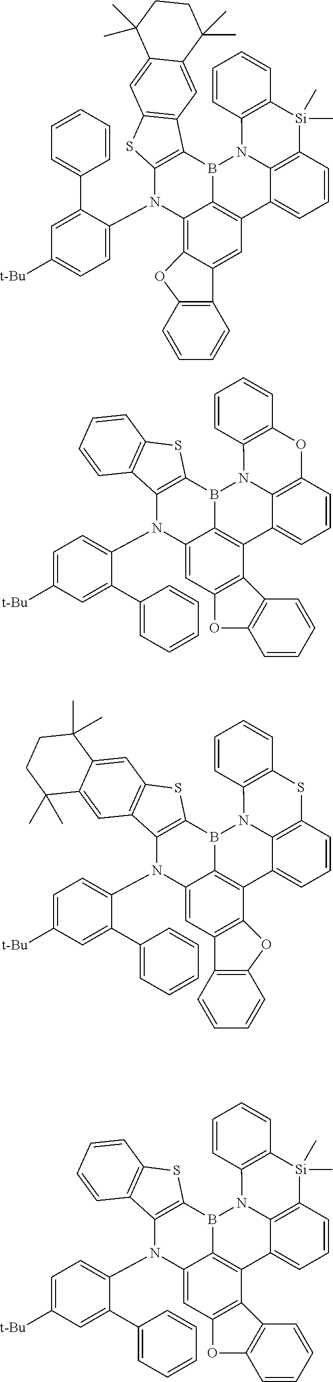 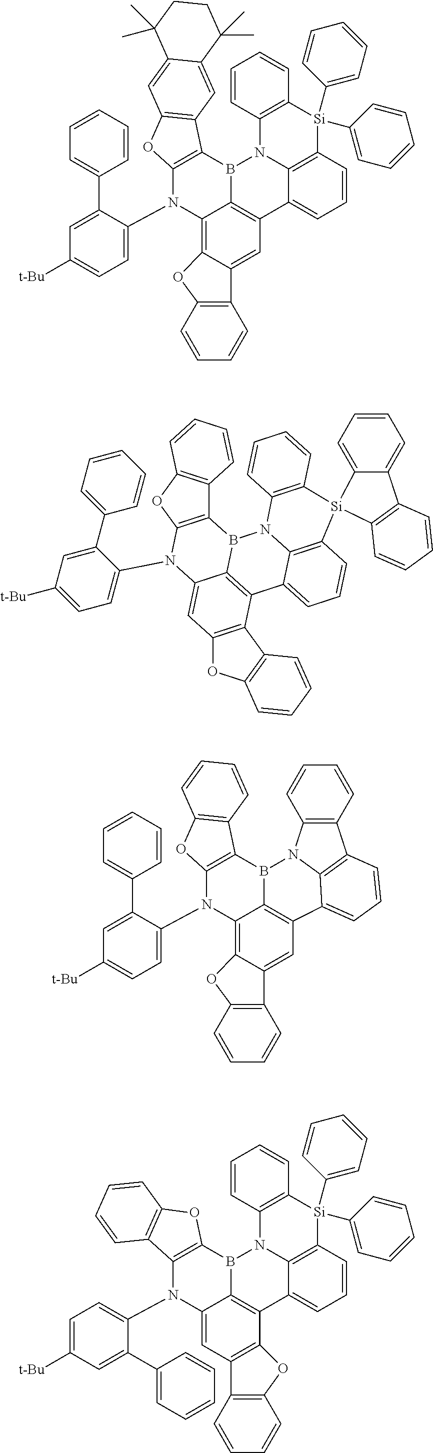 [SMILES: CC(C)(C)c1ccc(N2c3oc4cc5c(cc4c3B3c4c(cc6c(oc7ccccc76)c42)-c2cccc4c2N3c2ccccc2[Si]4(c2ccccc2)c2ccccc2)C(C)(C)CCC5(C)C)c(-c2ccccc2)c1 ; CC(C)(C)c1ccc(N2c3cc4oc5ccccc5c4c4c3B(c3c2oc2ccccc32)N2c3ccccc3[Si]3(c5ccccc5-c5ccccc53)c3cccc-4c32)c(-c2ccccc2)c1 ; CC(C)(C)c1ccc(N2c3oc4ccccc4c3B3c4c(cc5c(oc6ccccc65)c42)-c2cccc4c5ccccc5n3c24)c(-c2ccccc2)c1 ; CC(C)(C)c1ccc(N2c3cc4c(oc5ccccc54)c4c3B(c3oc5ccccc5c32)N2c3ccccc3[Si](c3ccccc3)(c3ccccc3)c3cccc-4c32)c(-c2ccccc2)c1] 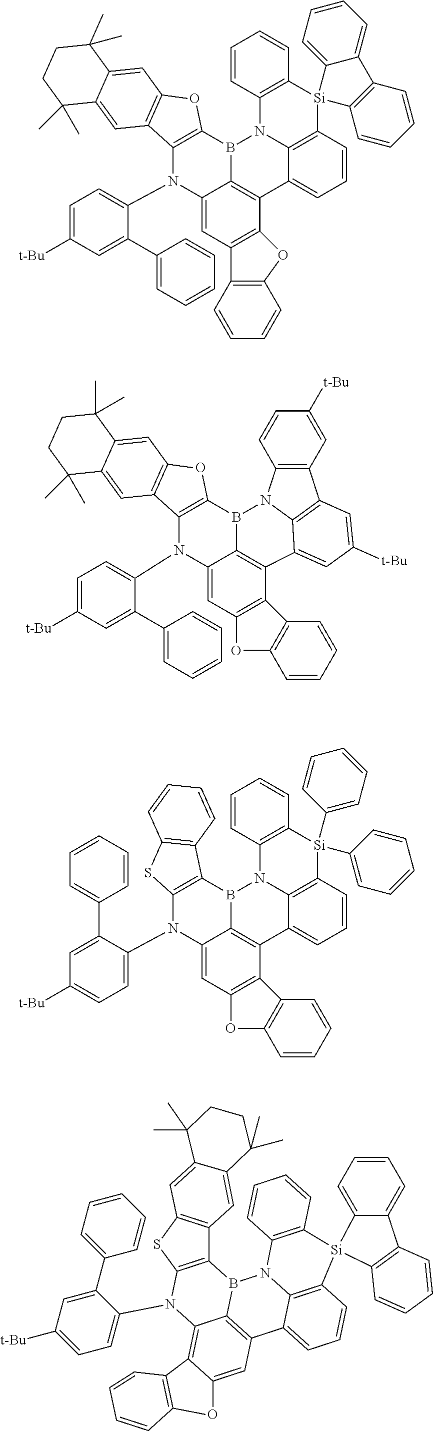 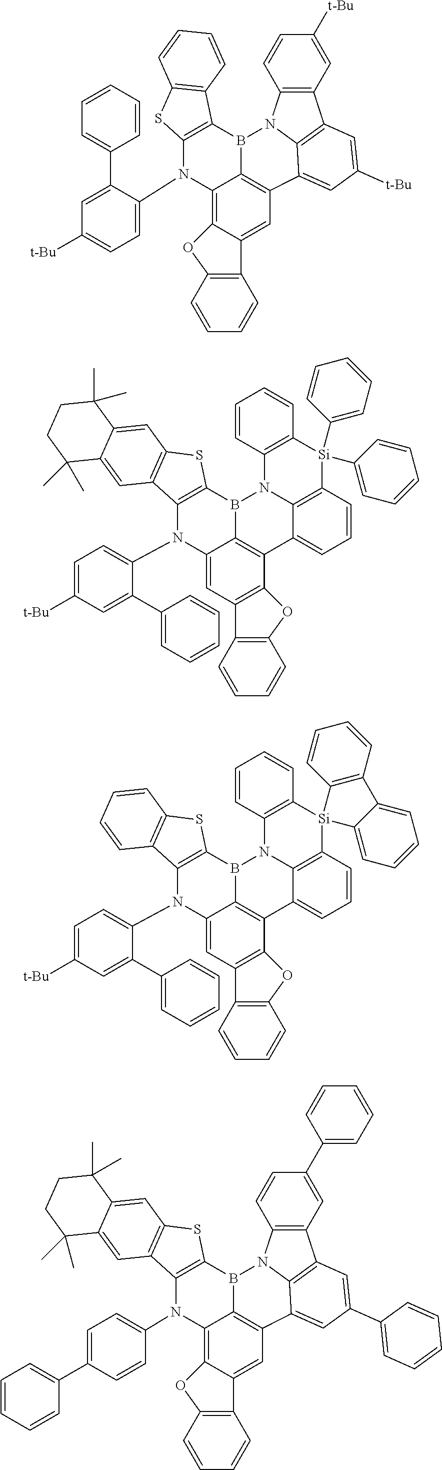 [SMILES: CC(C)(C)c1ccc(N2c3sc4ccccc4c3B3c4c(cc5c(oc6ccccc65)c42)-c2cc(C(C)(C)C)cc4c5cc(C(C)(C)C)ccc5n3c24)c(-c2ccccc2)c1 ; CC(C)(C)c1ccc(N2c3cc4c(oc5ccccc54)c4c3B(c3sc5cc6c(cc5c32)C(C)(C)CCC6(C)C)N2c3ccccc3[Si](c3ccccc3)(c3ccccc3)c3cccc-4c32)c(-c2ccccc2)c1 ; CC(C)(C)c1ccc(N2c3cc4c(oc5ccccc54)c4c3B(c3sc5ccccc5c32)N2c3ccccc3[Si]3(c5ccccc5-c5ccccc53)c3cccc-4c32)c(-c2ccccc2)c1 ; CC1(C)CCC(C)(C)c2cc3c4c(sc3cc21)B1c2c(cc3c(oc5ccccc53)c2N4c2ccc(-c3ccccc3)cc2)-c2cc(-c3ccccc3)cc3c4cc(-c5ccccc5)ccc4n1c23] 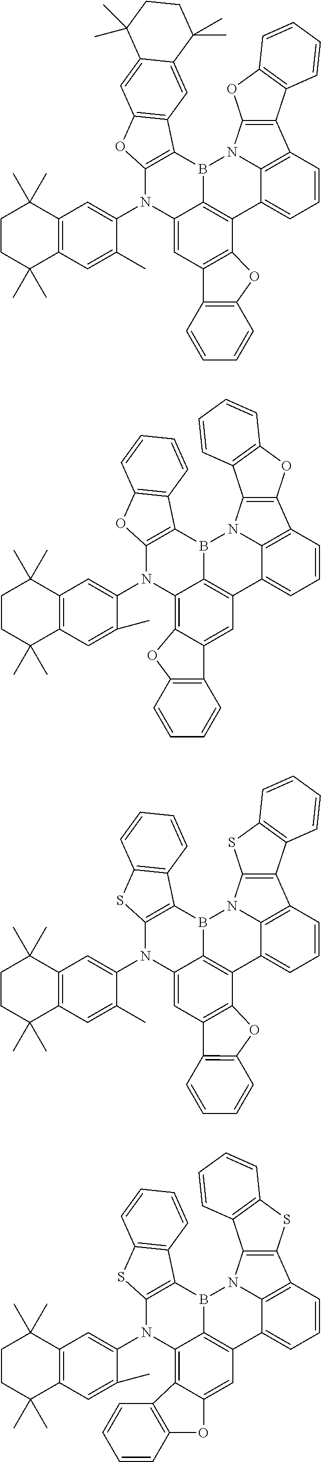 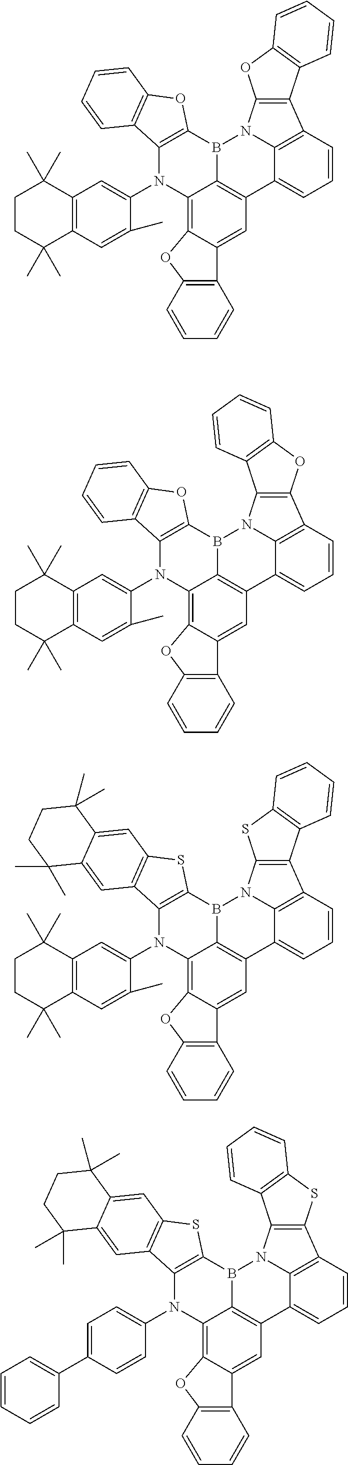 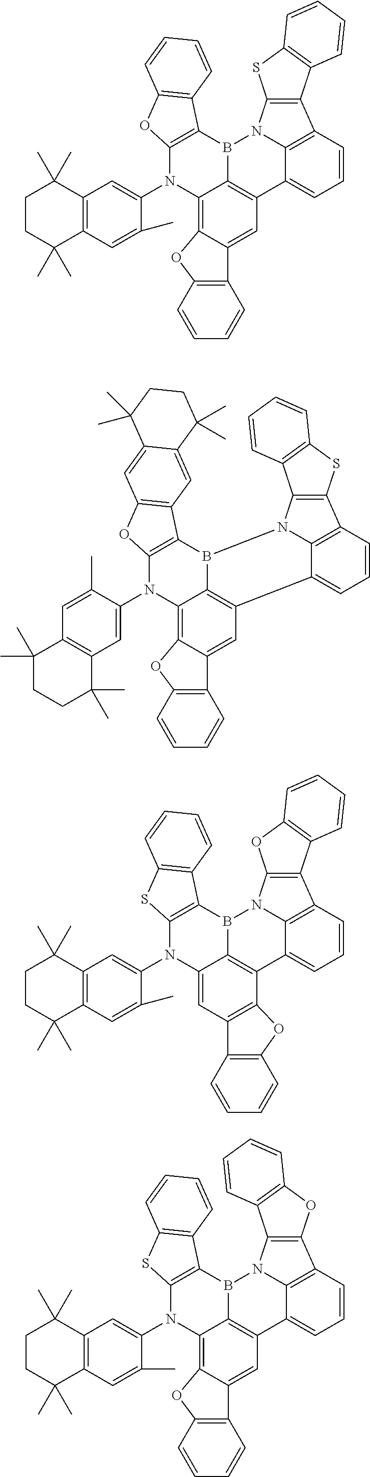 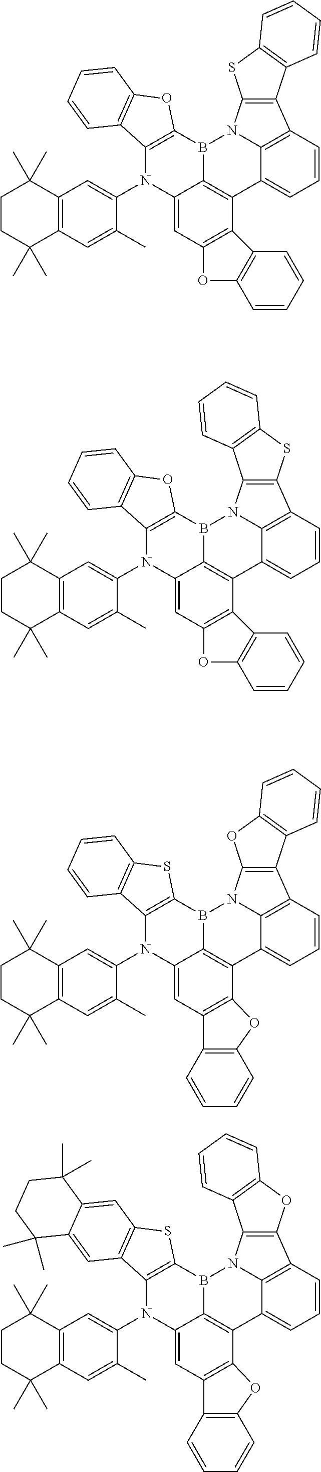 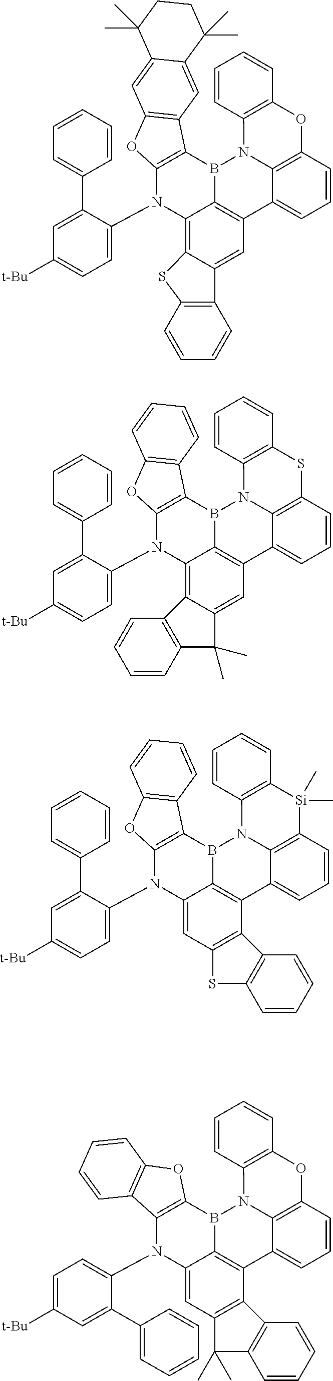 [SMILES: CC(C)(C)c1ccc(N2c3oc4cc5c(cc4c3B3c4c(cc6c(sc7ccccc76)c42)-c2cccc4c2N3c2ccccc2O4)C(C)(C)CCC5(C)C)c(-c2ccccc2)c1 ; CC(C)(C)c1ccc(N2c3oc4ccccc4c3B3c4c(cc5c(c42)-c2ccccc2C5(C)C)-c2cccc4c2N3c2ccccc2S4)c(-c2ccccc2)c1 ; CC(C)(C)c1ccc(N2c3cc4sc5ccccc5c4c4c3B(c3c2oc2ccccc32)N2c3ccccc3[Si](C)(C)c3cccc-4c32)c(-c2ccccc2)c1 ; CC(C)(C)c1ccc(N2c3cc4c(c5c3B(c3oc6ccccc6c32)N2c3ccccc3Oc3cccc-5c32)-c2ccccc2C4(C)C)c(-c2ccccc2)c1] 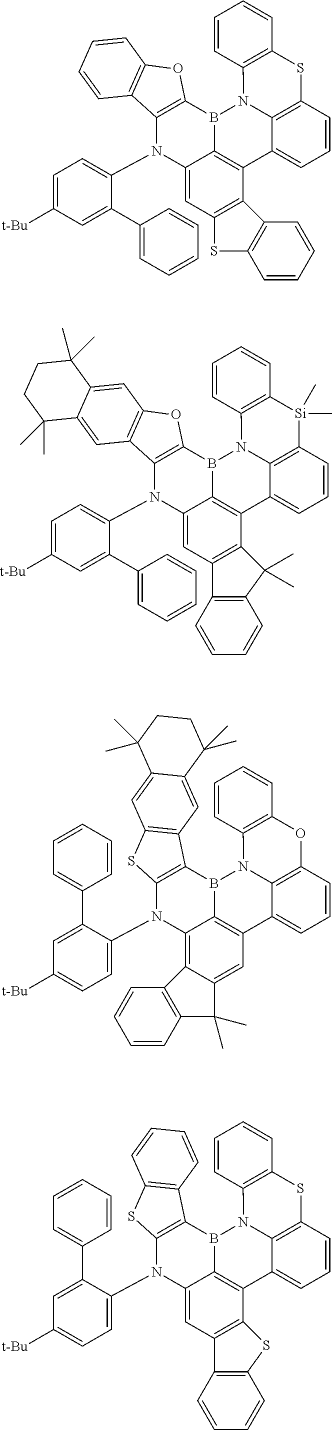 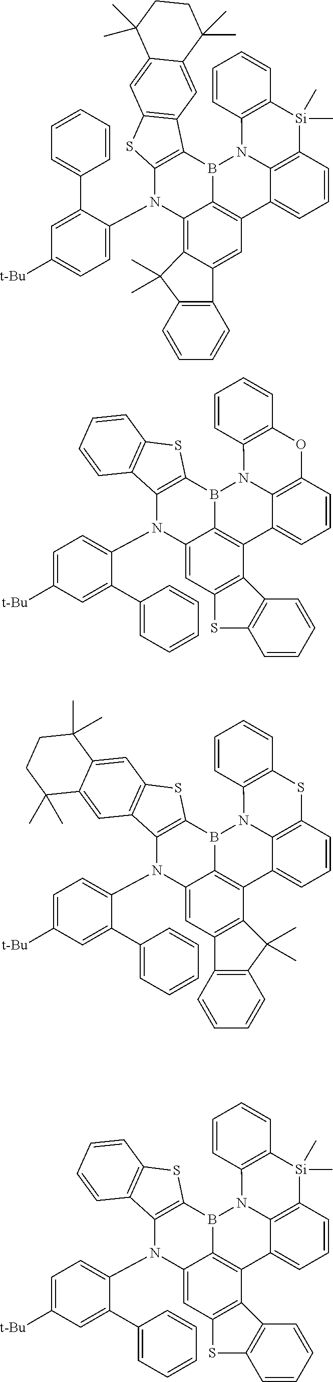 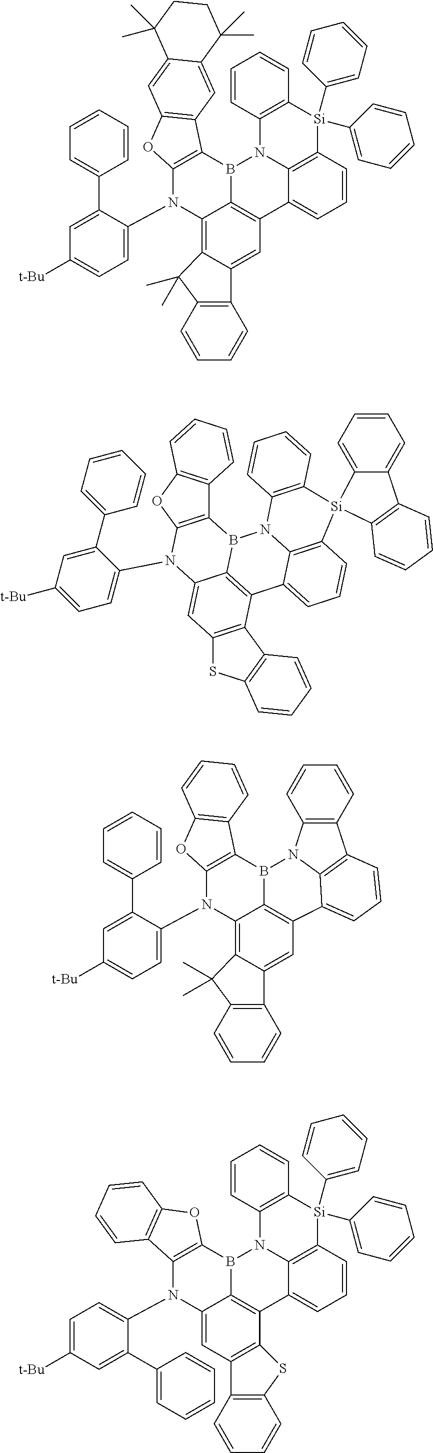 [SMILES: CC(C)(C)c1ccc(N2c3oc4cc5c(cc4c3B3c4c(cc6c(c42)C(C)(C)c2ccccc2-6)-c2cccc4c2N3c2ccccc2[Si]4(c2ccccc2)c2ccccc2)C(C)(C)CCC5(C)C)c(-c2ccccc2)c1 ; CC(C)(C)c1ccc(N2c3cc4sc5ccccc5c4c4c3B(c3c2oc2ccccc32)N2c3ccccc3[Si]3(c5ccccc5-c5ccccc53)c3cccc-4c32)c(-c2ccccc2)c1 ; CC(C)(C)c1ccc(N2c3oc4ccccc4c3B3c4c(cc5c(c42)C(C)(C)c2ccccc2-5)-c2cccc4c5ccccc5n3c24)c(-c2ccccc2)c1 ; CC(C)(C)c1ccc(N2c3cc4c(sc5ccccc54)c4c3B(c3oc5ccccc5c32)N2c3ccccc3[Si](c3ccccc3)(c3ccccc3)c3cccc-4c32)c(-c2ccccc2)c1] 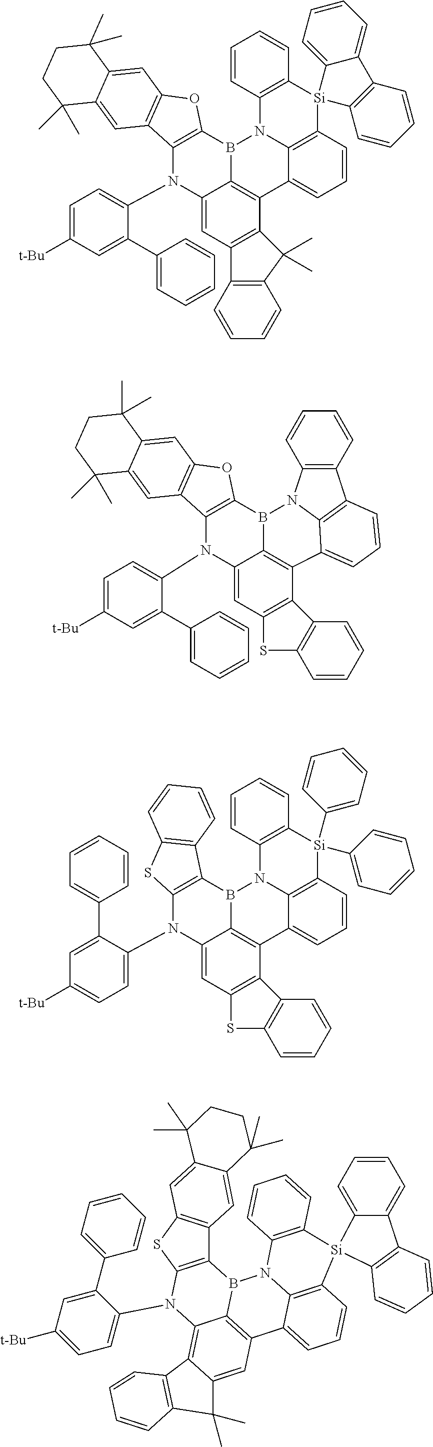 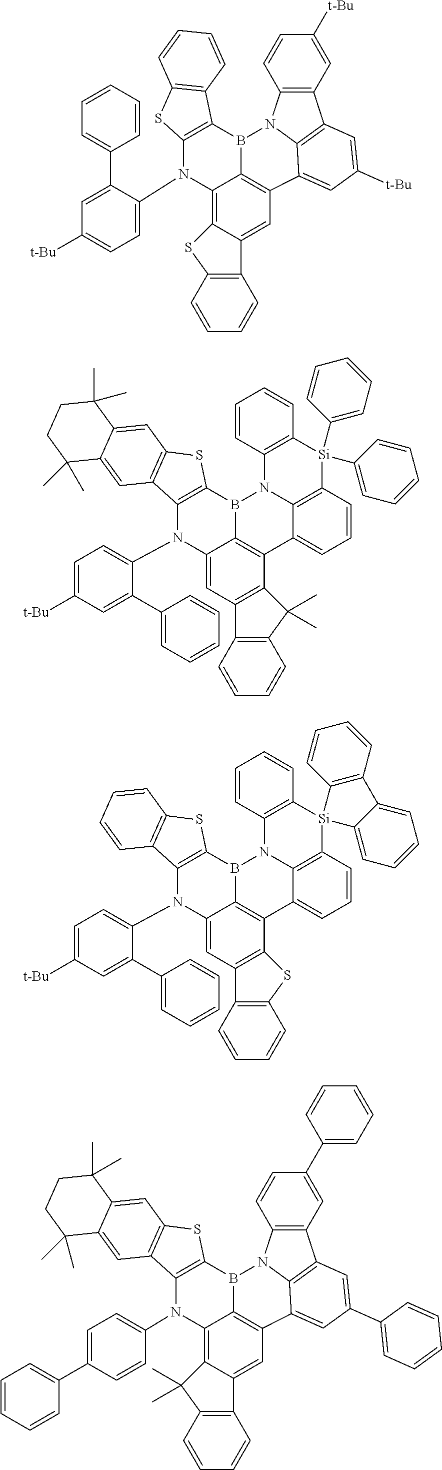 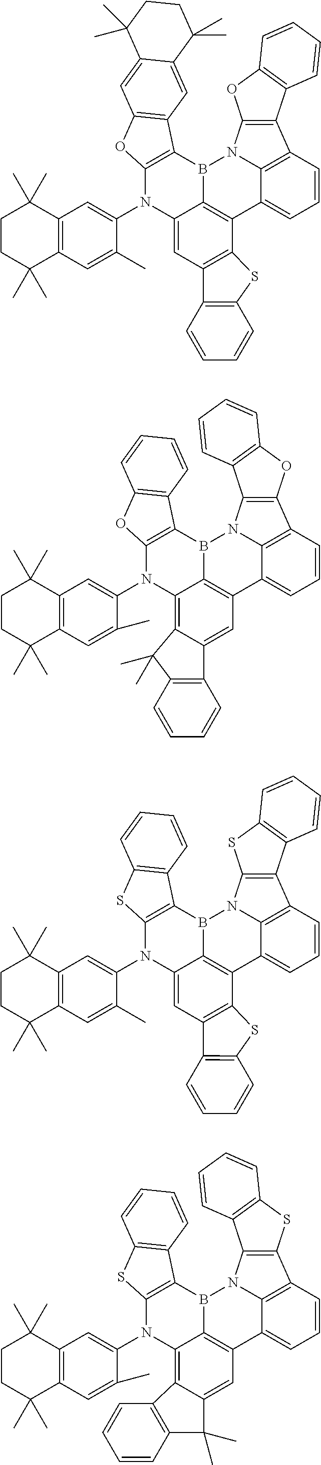 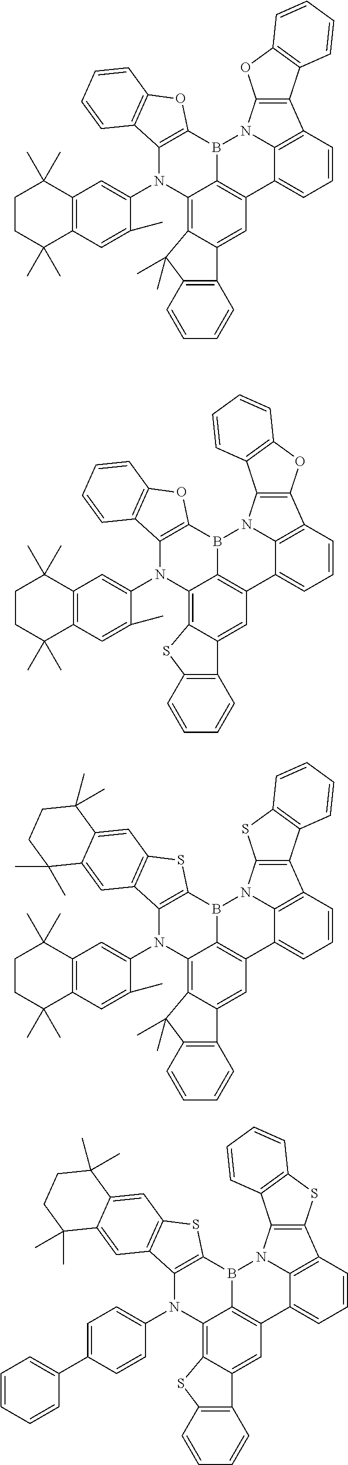 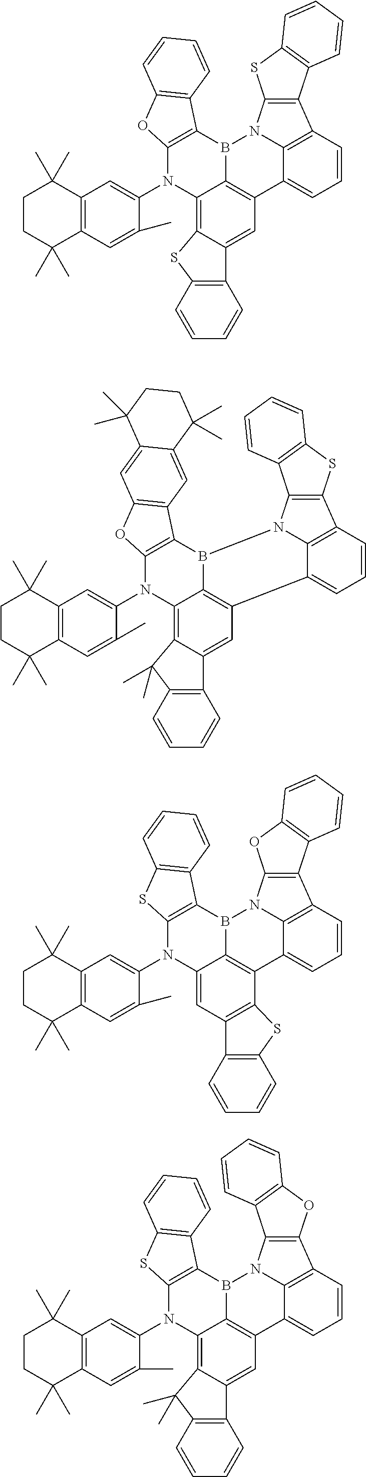 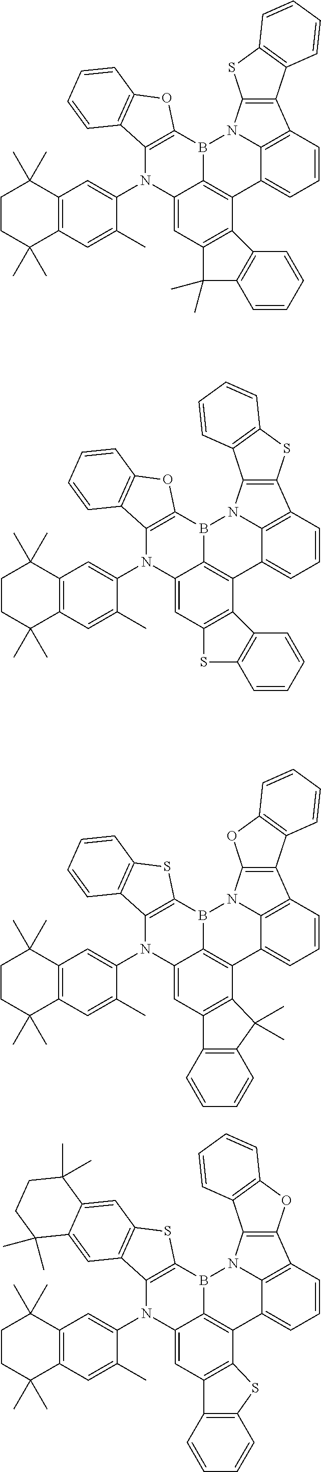 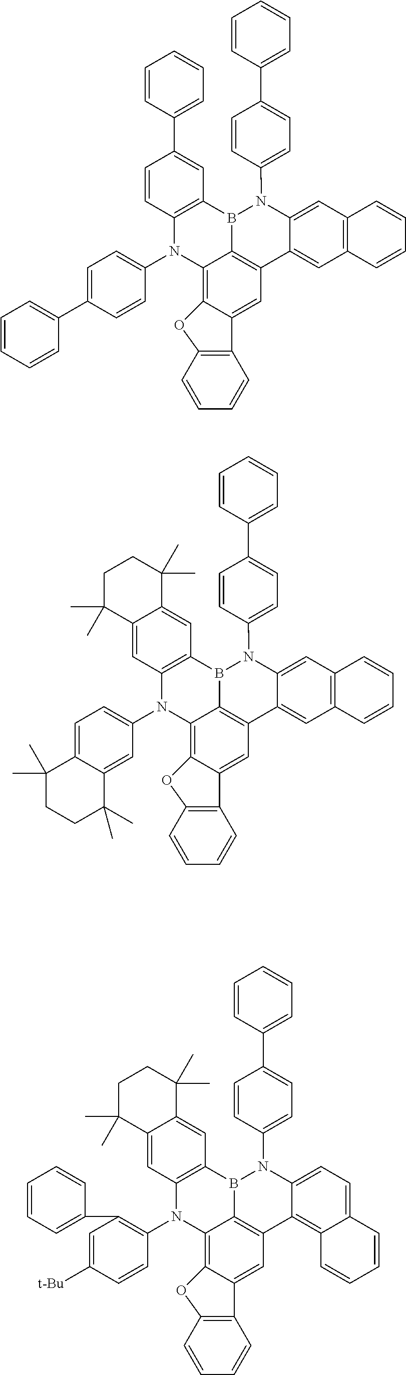 [SMILES: c1ccc(-c2ccc(N3B4c5cc(-c6ccccc6)ccc5N(c5ccc(-c6ccccc6)cc5)c5c4c(cc4c5oc5ccccc54)-c4cc5ccccc5cc43)cc2)cc1 ; CC1(C)CCC(C)(C)c2cc(N3c4cc5c(cc4B4c6c(cc7c(oc8ccccc87)c63)-c3cc6ccccc6cc3N4c3ccc(-c4ccccc4)cc3)C(C)(C)CCC5(C)C)ccc21 ; CC(C)(C)c1ccc(N2c3cc4c(cc3B3c5c(cc6c(oc7ccccc76)c52)-c2c(ccc5ccccc25)N3c2ccc(-c3ccccc3)cc2)C(C)(C)CCC4(C)C)c(-c2ccccc2)c1] 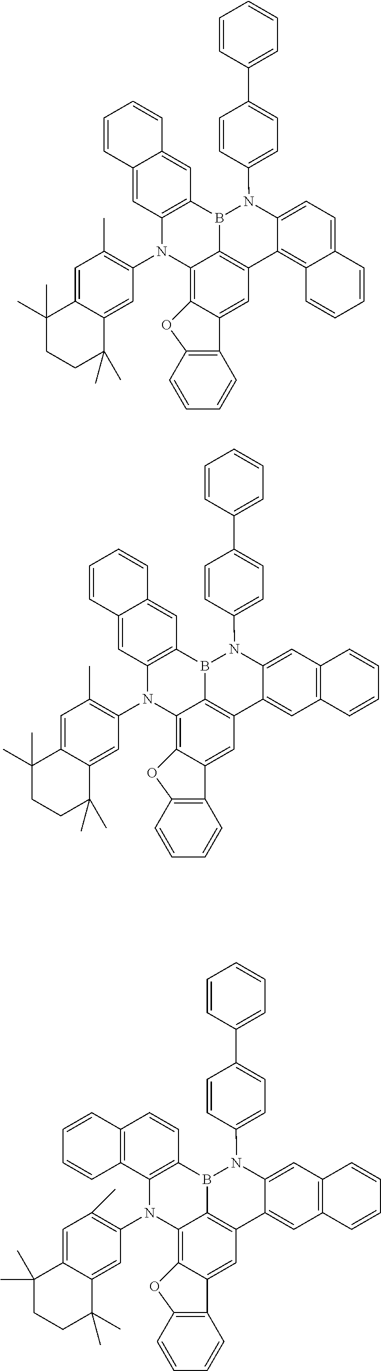 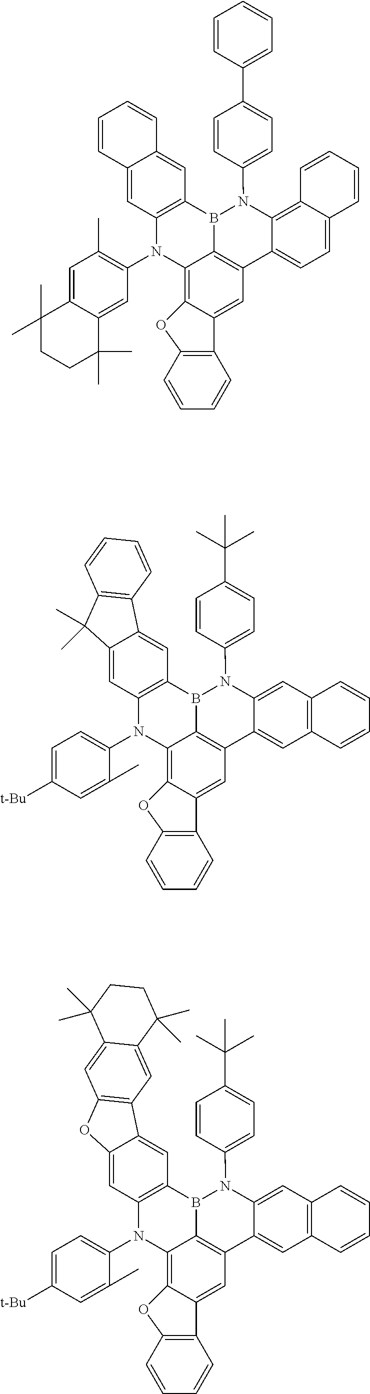 [SMILES: Cc1cc2c(cc1N1c3cc4ccccc4cc3B3c4c(cc5c(oc6ccccc65)c41)-c1ccc4ccccc4c1N3c1ccc(-c3ccccc3)cc1)C(C)(C)CCC2(C)C ; Cc1cc(C(C)(C)C)ccc1N1c2cc3c(cc2B2c4c(cc5c(oc6ccccc65)c41)-c1cc4ccccc4cc1N2c1ccc(C(C)(C)C)cc1)-c1ccccc1C3(C)C ; Cc1cc(C(C)(C)C)ccc1N1c2cc3oc4cc5c(cc4c3cc2B2c3c(cc4c(oc6ccccc64)c31)-c1cc3ccccc3cc1N2c1ccc(C(C)(C)C)cc1)C(C)(C)CCC5(C)C] 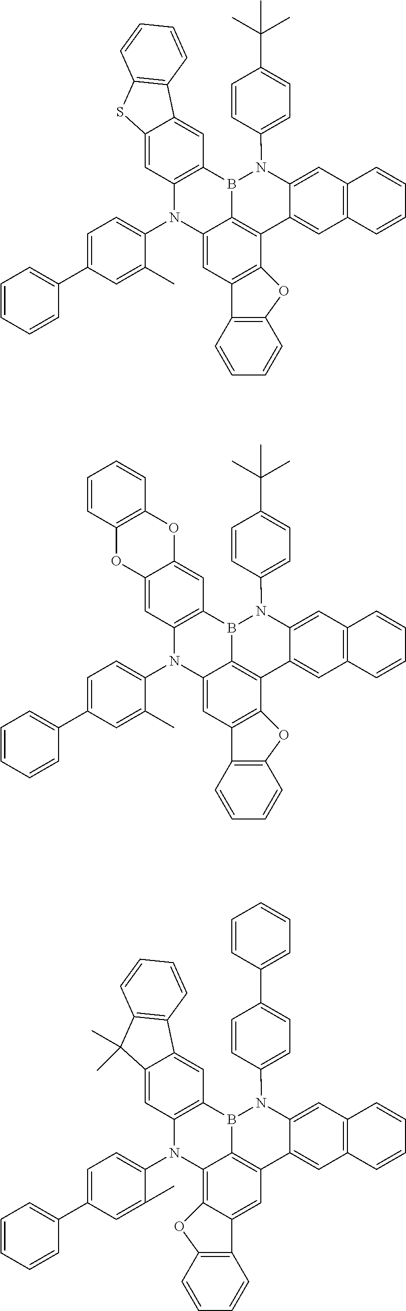 [SMILES: Cc1cc(-c2ccccc2)ccc1N1c2cc3sc4ccccc4c3cc2B2c3c1cc1c(oc4ccccc41)c3-c1cc3ccccc3cc1N2c1ccc(C(C)(C)C)cc1 ; Cc1cc(-c2ccccc2)ccc1N1c2cc3c(cc2B2c4c1cc1c(oc5ccccc51)c4-c1cc4ccccc4cc1N2c1ccc(C(C)(C)C)cc1)Oc1ccccc1O3 ; Cc1cc(-c2ccccc2)ccc1N1c2cc3c(cc2B2c4c(cc5c(oc6ccccc65)c41)-c1cc4ccccc4cc1N2c1ccc(-c2ccccc2)cc1)-c1ccccc1C3(C)C] 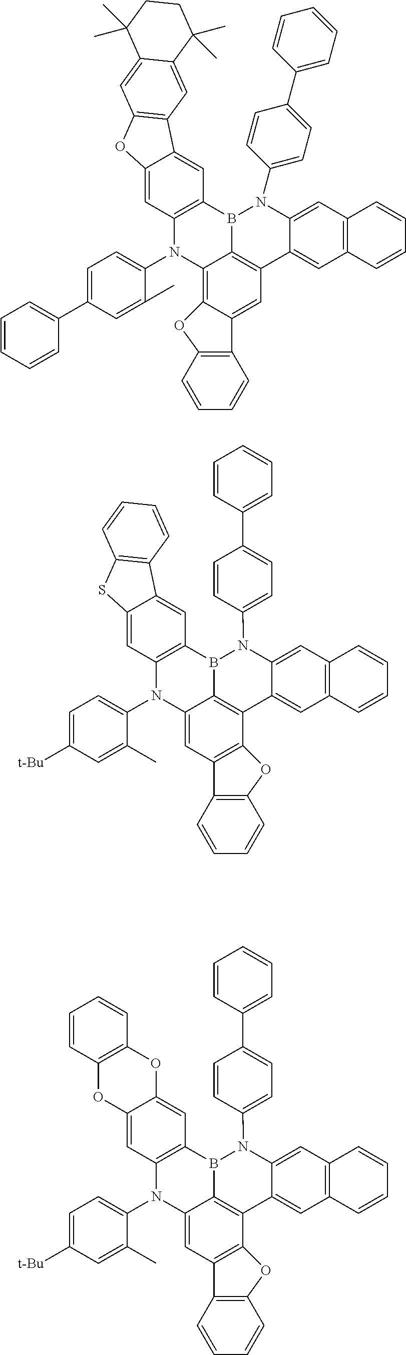 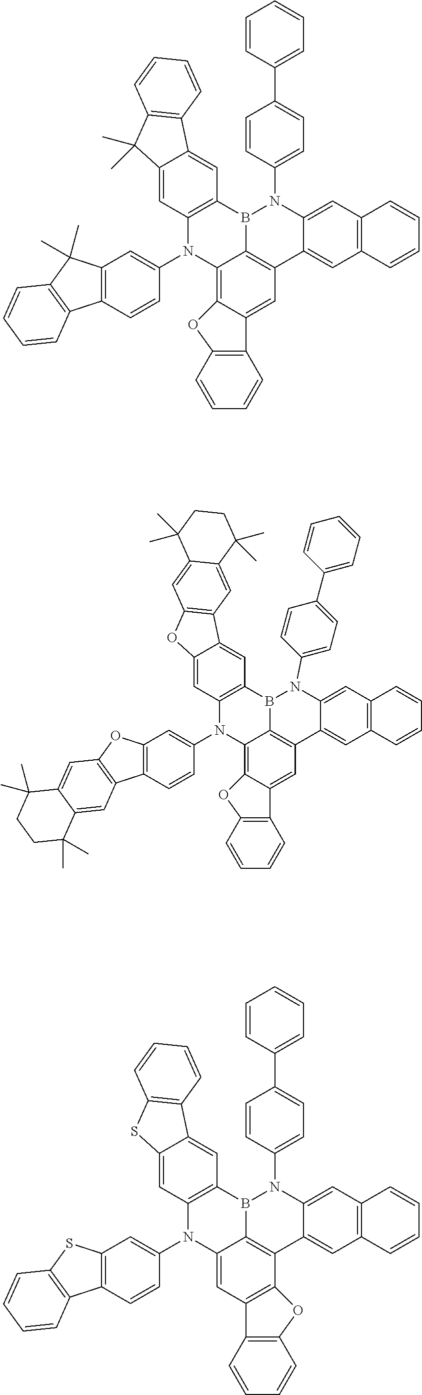 [SMILES: CC1(C)c2ccccc2-c2ccc(N3c4cc5c(cc4B4c6c(cc7c(oc8ccccc87)c63)-c3cc6ccccc6cc3N4c3ccc(-c4ccccc4)cc3)-c3ccccc3C5(C)C)cc21 ; CC1(C)CCC(C)(C)c2cc3c(cc21)oc1cc(N2c4cc5oc6cc7c(cc6c5cc4B4c5c(cc6c(oc8ccccc86)c52)-c2cc5ccccc5cc2N4c2ccc(-c4ccccc4)cc2)C(C)(C)CCC7(C)C)ccc13 ; c1ccc(-c2ccc(N3B4c5cc6c(cc5N(c5ccc7c(c5)sc5ccccc57)c5cc7c(oc8ccccc87)c(c54)-c4cc5ccccc5cc43)sc3ccccc36)cc2)cc1] 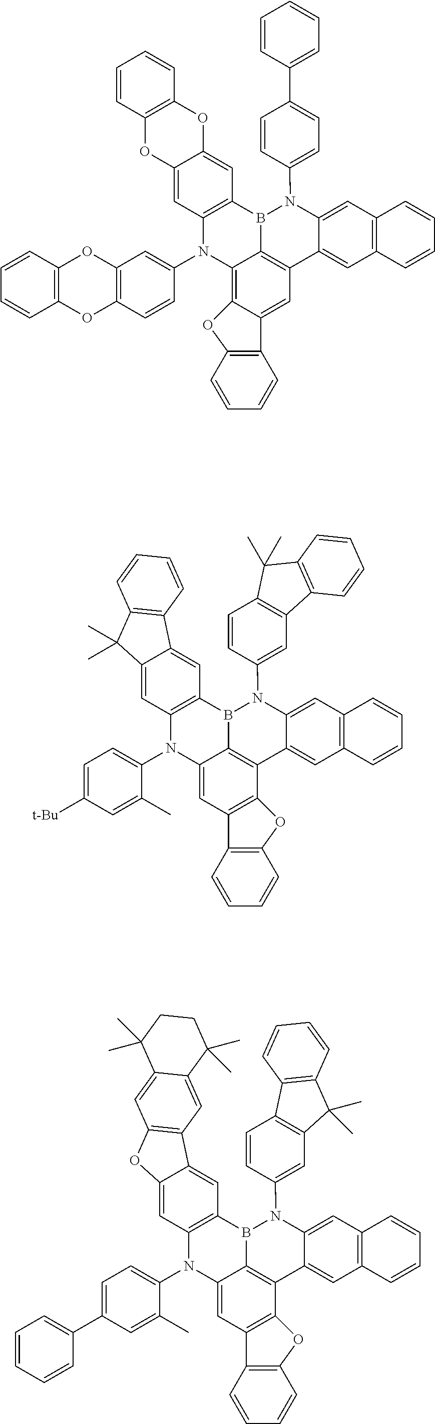 [SMILES: c1ccc(-c2ccc(N3B4c5cc6c(cc5N(c5ccc7c(c5)Oc5ccccc5O7)c5c4c(cc4c5oc5ccccc54)-c4cc5ccccc5cc43)Oc3ccccc3O6)cc2)cc1 ; Cc1cc(C(C)(C)C)ccc1N1c2cc3c(cc2B2c4c1cc1c(oc5ccccc51)c4-c1cc4ccccc4cc1N2c1ccc2c(c1)-c1ccccc1C2(C)C)-c1ccccc1C3(C)C ; Cc1cc(-c2ccccc2)ccc1N1c2cc3oc4cc5c(cc4c3cc2B2c3c1cc1c(oc4ccccc41)c3-c1cc3ccccc3cc1N2c1ccc2c(c1)C(C)(C)c1ccccc1-2)C(C)(C)CCC5(C)C] 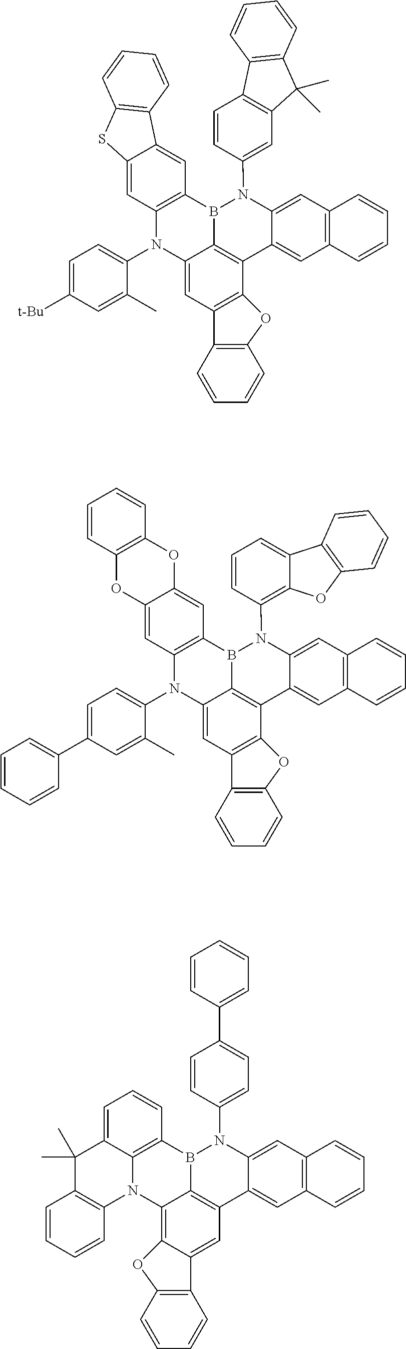 [SMILES: Cc1cc(C(C)(C)C)ccc1N1c2cc3sc4ccccc4c3cc2B2c3c1cc1c(oc4ccccc41)c3-c1cc3ccccc3cc1N2c1ccc2c(c1)C(C)(C)c1ccccc1-2 ; Cc1cc(-c2ccccc2)ccc1N1c2cc3c(cc2B2c4c1cc1c(oc5ccccc51)c4-c1cc4ccccc4cc1N2c1cccc2c1oc1ccccc12)Oc1ccccc1O3 ; CC1(C)c2ccccc2N2c3c(cccc31)B1c3c(cc4c(oc5ccccc54)c32)-c2cc3ccccc3cc2N1c1ccc(-c2ccccc2)cc1] 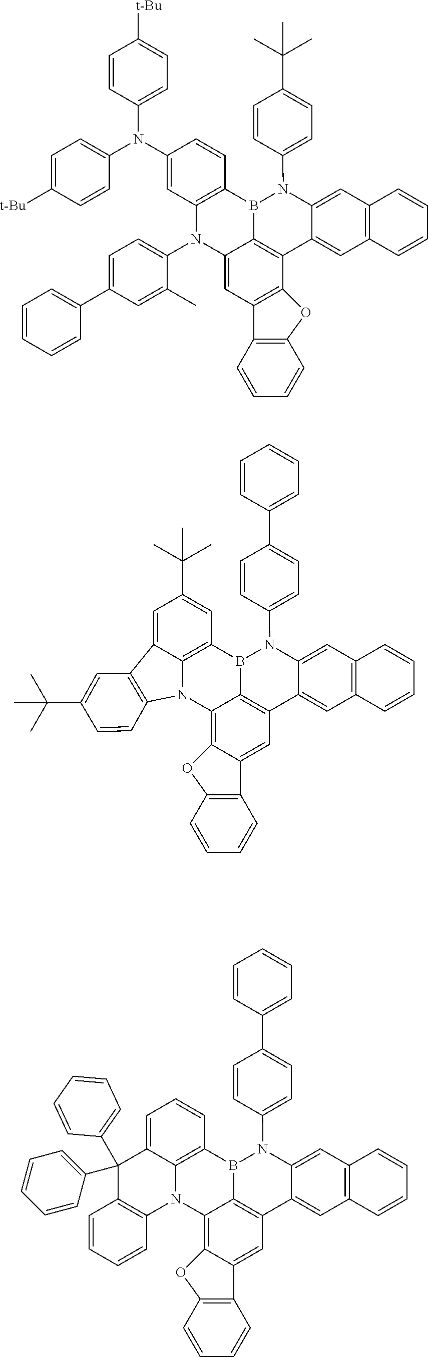 [SMILES: Cc1cc(-c2ccccc2)ccc1N1c2cc(N(c3ccc(C(C)(C)C)cc3)c3ccc(C(C)(C)C)cc3)ccc2B2c3c1cc1c(oc4ccccc41)c3-c1cc3ccccc3cc1N2c1ccc(C(C)(C)C)cc1 ; CC(C)(C)c1ccc2c(c1)c1cc(C(C)(C)C)cc3c1n2-c1c2c(cc4c1oc1ccccc14)-c1cc4ccccc4cc1N(c1ccc(-c4ccccc4)cc1)B23 ; c1ccc(-c2ccc(N3B4c5cccc6c5N(c5ccccc5C6(c5ccccc5)c5ccccc5)c5c4c(cc4c5oc5ccccc54)-c4cc5ccccc5cc43)cc2)cc1] 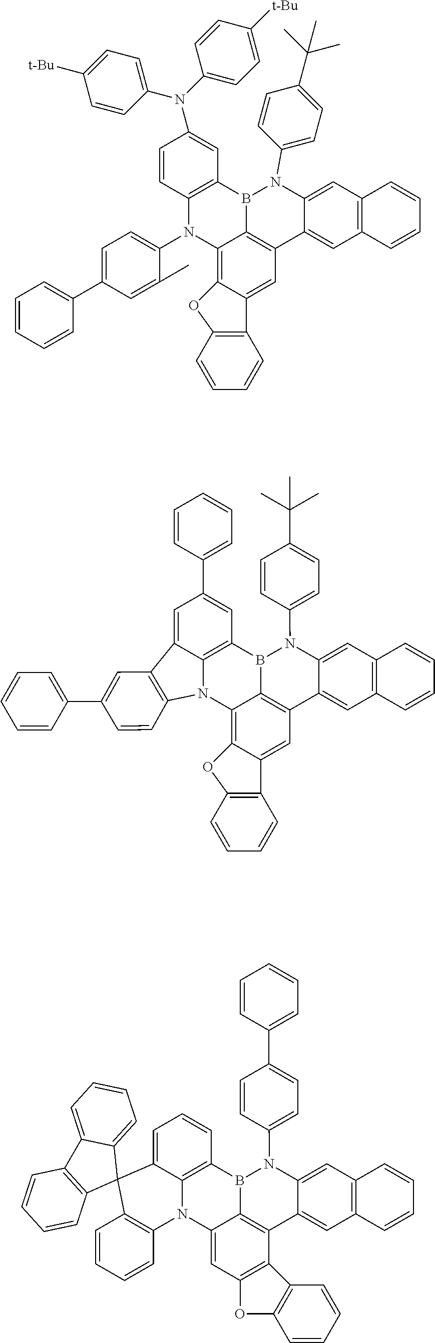 [SMILES: Cc1cc(-c2ccccc2)ccc1N1c2ccc(N(c3ccc(C(C)(C)C)cc3)c3ccc(C(C)(C)C)cc3)cc2B2c3c(cc4c(oc5ccccc54)c31)-c1cc3ccccc3cc1N2c1ccc(C(C)(C)C)cc1 ; CC(C)(C)c1ccc(N2B3c4c(cc5c(oc6ccccc65)c4-n4c5ccc(-c6ccccc6)cc5c5cc(-c6ccccc6)cc3c54)-c3cc4ccccc4cc32)cc1 ; c1ccc(-c2ccc(N3B4c5cccc6c5N(c5ccccc5C65c6ccccc6-c6ccccc65)c5cc6oc7ccccc7c6c(c54)-c4cc5ccccc5cc43)cc2)cc1] 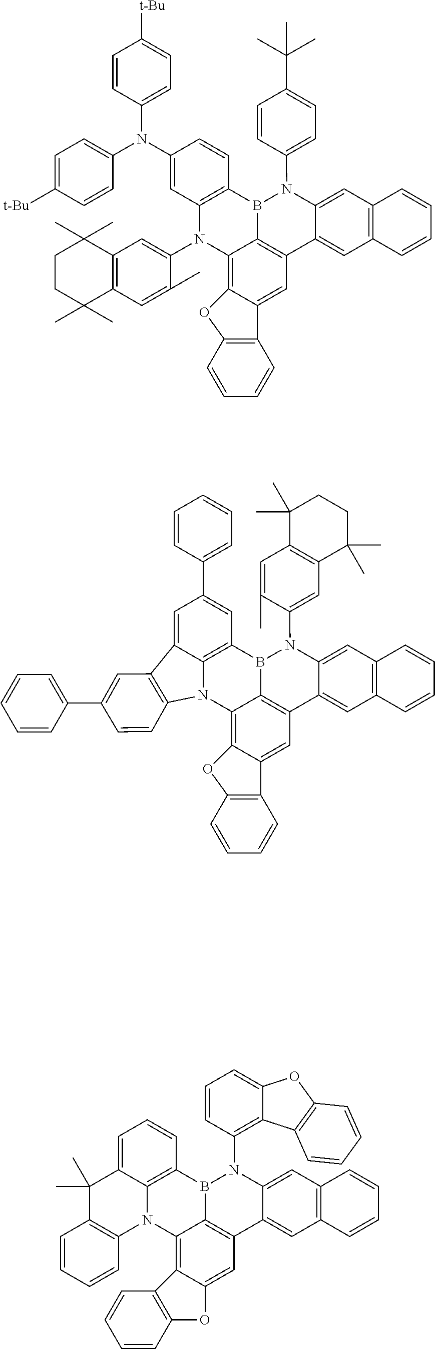 [SMILES: Cc1cc2c(cc1N1c3cc(N(c4ccc(C(C)(C)C)cc4)c4ccc(C(C)(C)C)cc4)ccc3B3c4c(cc5c(oc6ccccc65)c41)-c1cc4ccccc4cc1N3c1ccc(C(C)(C)C)cc1)C(C)(C)CCC2(C)C ; Cc1cc2c(cc1N1B3c4c(cc5c(oc6ccccc65)c4-n4c5ccc(-c6ccccc6)cc5c5cc(-c6ccccc6)cc3c54)-c3cc4ccccc4cc31)C(C)(C)CCC2(C)C ; CC1(C)c2ccccc2N2c3c(cccc31)B1c3c(cc4oc5ccccc5c4c32)-c2cc3ccccc3cc2N1c1cccc2oc3ccccc3c12] 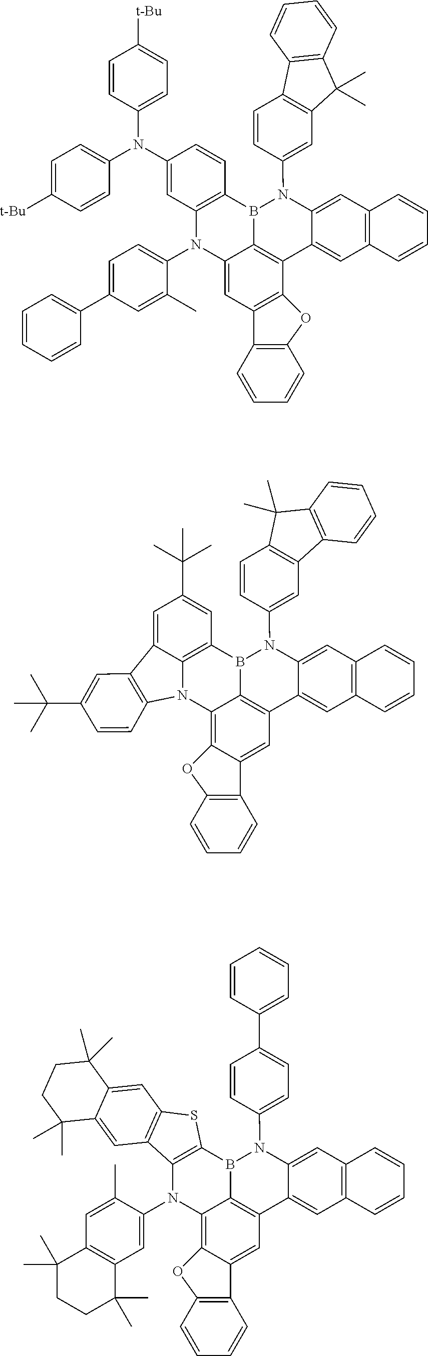 [SMILES: Cc1cc(-c2ccccc2)ccc1N1c2cc(N(c3ccc(C(C)(C)C)cc3)c3ccc(C(C)(C)C)cc3)ccc2B2c3c1cc1c(oc4ccccc41)c3-c1cc3ccccc3cc1N2c1ccc2c(c1)C(C)(C)c1ccccc1-2 ; CC(C)(C)c1ccc2c(c1)c1cc(C(C)(C)C)cc3c1n2-c1c2c(cc4c1oc1ccccc14)-c1cc4ccccc4cc1N(c1ccc4c(c1)-c1ccccc1C4(C)C)B23 ; Cc1cc2c(cc1N1c3c(sc4cc5c(cc34)C(C)(C)CCC5(C)C)B3c4c(cc5c(oc6ccccc65)c41)-c1cc4ccccc4cc1N3c1ccc(-c3ccccc3)cc1)C(C)(C)CCC2(C)C] 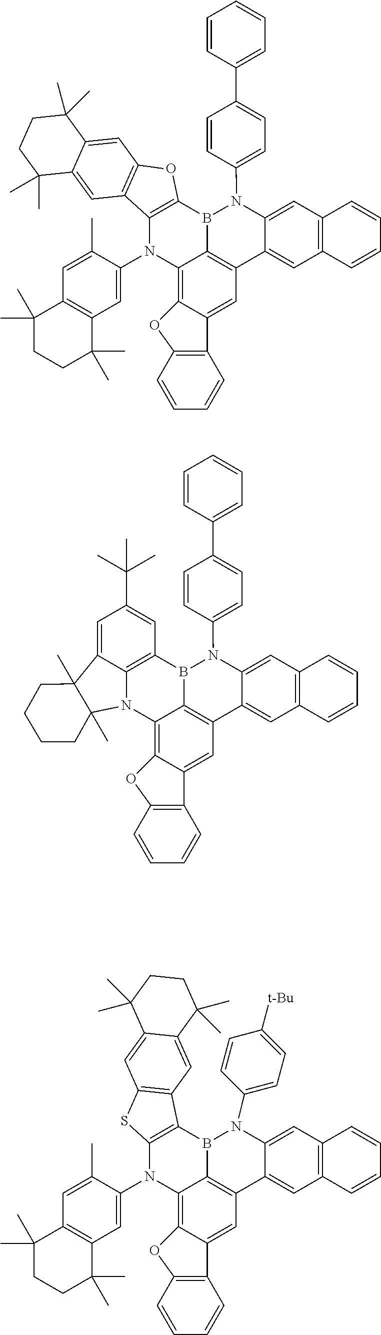 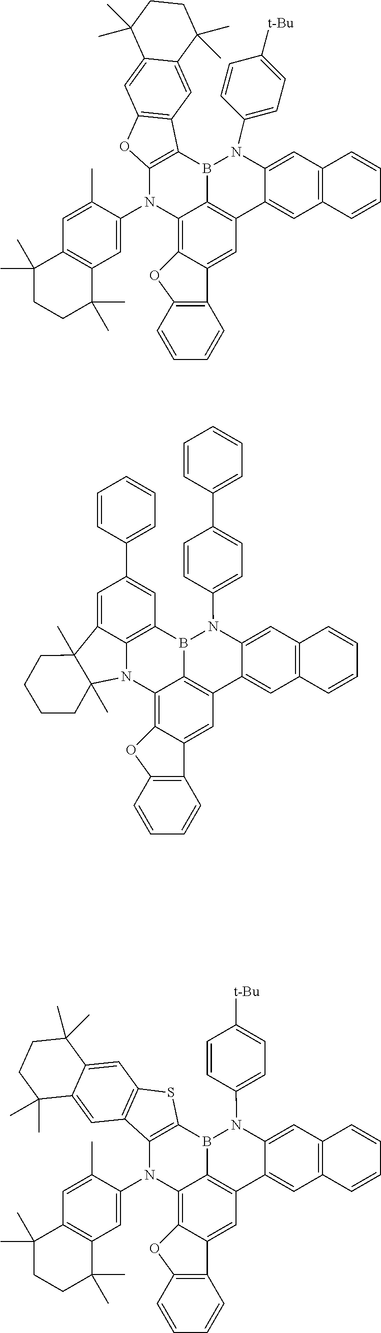 [SMILES: Cc1cc2c(cc1N1c3oc4cc5c(cc4c3B3c4c(cc6c(oc7ccccc76)c41)-c1cc4ccccc4cc1N3c1ccc(C(C)(C)C)cc1)C(C)(C)CCC5(C)C)C(C)(C)CCC2(C)C ; CC12CCCCC1(C)N1c3c(cc(-c4ccccc4)cc32)B2c3c(cc4c(oc5ccccc54)c31)-c1cc3ccccc3cc1N2c1ccc(-c2ccccc2)cc1 ; Cc1cc2c(cc1N1c3c(sc4cc5c(cc34)C(C)(C)CCC5(C)C)B3c4c(cc5c(oc6ccccc65)c41)-c1cc4ccccc4cc1N3c1ccc(C(C)(C)C)cc1)C(C)(C)CCC2(C)C] 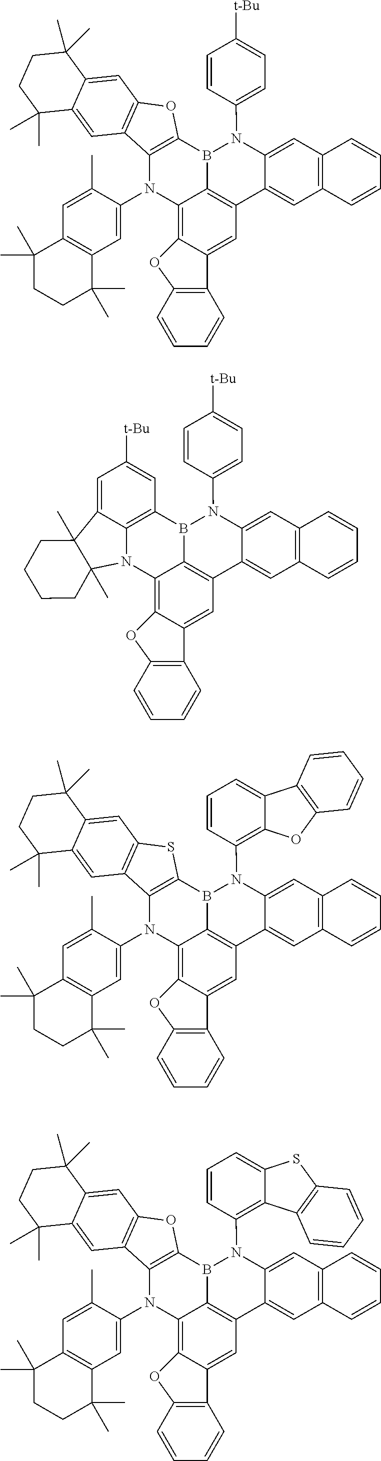 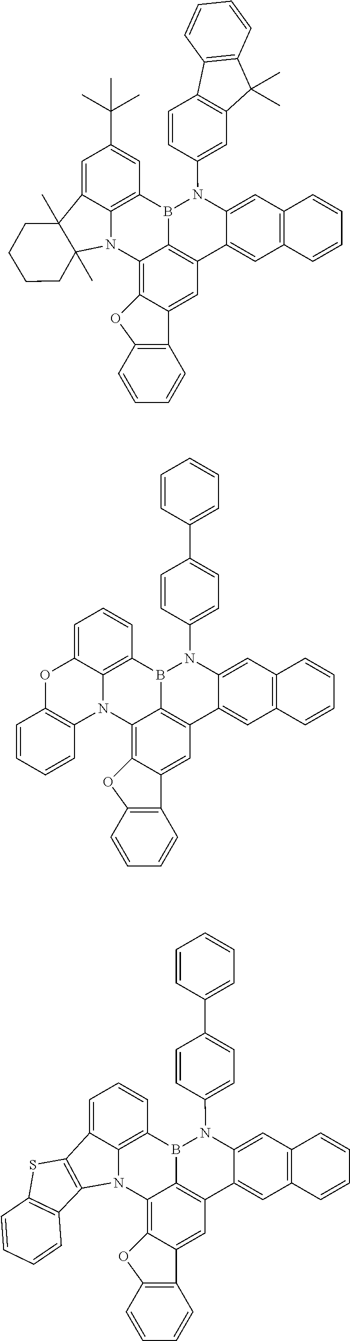 [SMILES: CC(C)(C)c1cc2c3c(c1)C1(C)CCCCC1(C)N3c1c3c(cc4c1oc1ccccc14)-c1cc4ccccc4cc1N(c1ccc4c(c1)C(C)(C)c1ccccc1-4)B23 ; c1ccc(-c2ccc(N3B4c5cccc6c5N(c5ccccc5O6)c5c4c(cc4c5oc5ccccc54)-c4cc5ccccc5cc43)cc2)cc1 ; c1ccc(-c2ccc(N3B4c5c(cc6c(oc7ccccc76)c5-n5c6c4cccc6c4sc6ccccc6c45)-c4cc5ccccc5cc43)cc2)cc1] 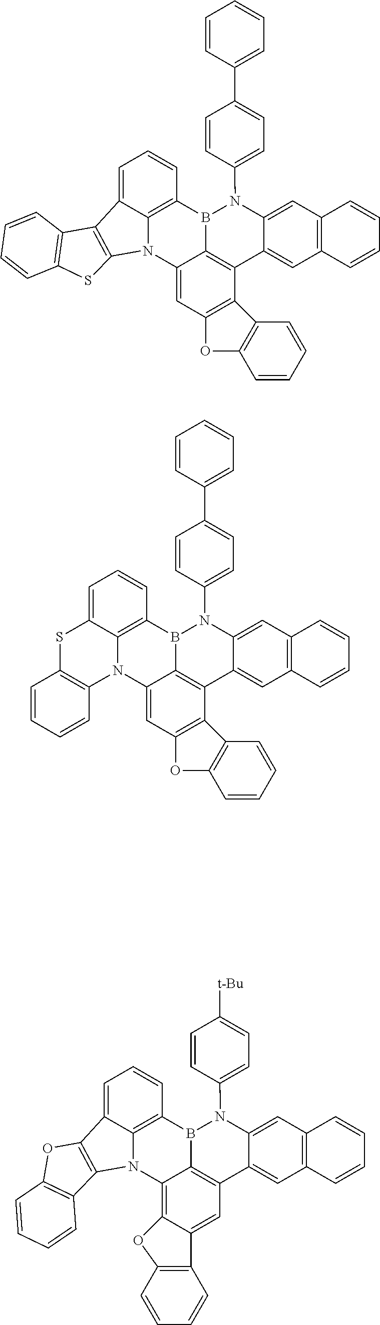 [SMILES: c1ccc(-c2ccc(N3B4c5c(cc6oc7ccccc7c6c5-c5cc6ccccc6cc53)-n3c5sc6ccccc6c5c5cccc4c53)cc2)cc1 ; c1ccc(-c2ccc(N3B4c5cccc6c5N(c5ccccc5S6)c5cc6oc7ccccc7c6c(c54)-c4cc5ccccc5cc43)cc2)cc1 ; CC(C)(C)c1ccc(N2B3c4c(cc5c(oc6ccccc65)c4-n4c5c3cccc5c3oc5ccccc5c34)-c3cc4ccccc4cc32)cc1] 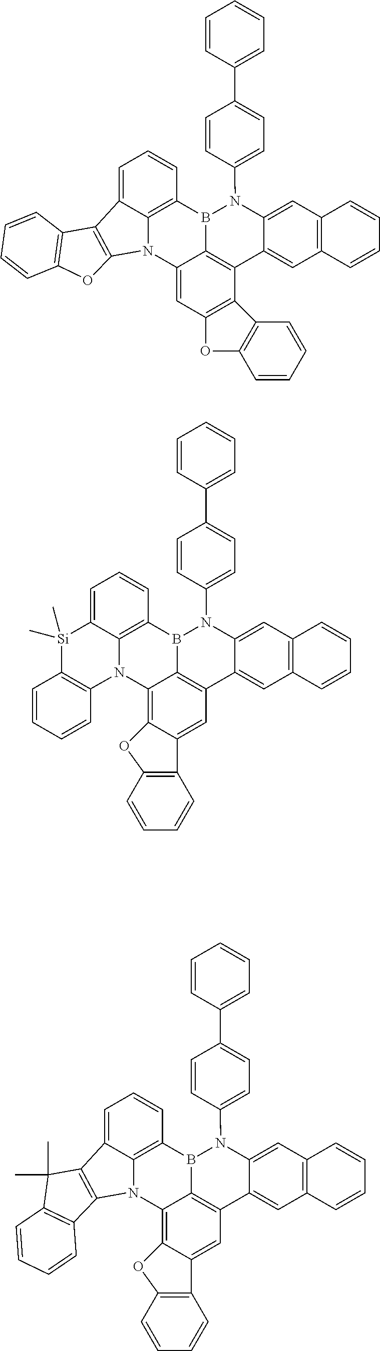 [SMILES: c1ccc(-c2ccc(N3B4c5c(cc6oc7ccccc7c6c5-c5cc6ccccc6cc53)-n3c5oc6ccccc6c5c5cccc4c53)cc2)cc1 ; C[Si]1(C)c2ccccc2N2c3c(cccc31)B1c3c(cc4c(oc5ccccc54)c32)-c2cc3ccccc3cc2N1c1ccc(-c2ccccc2)cc1 ; CC1(C)c2ccccc2-c2c1c1cccc3c1n2-c1c2c(cc4c1oc1ccccc14)-c1cc4ccccc4cc1N(c1ccc(-c4ccccc4)cc1)B23] 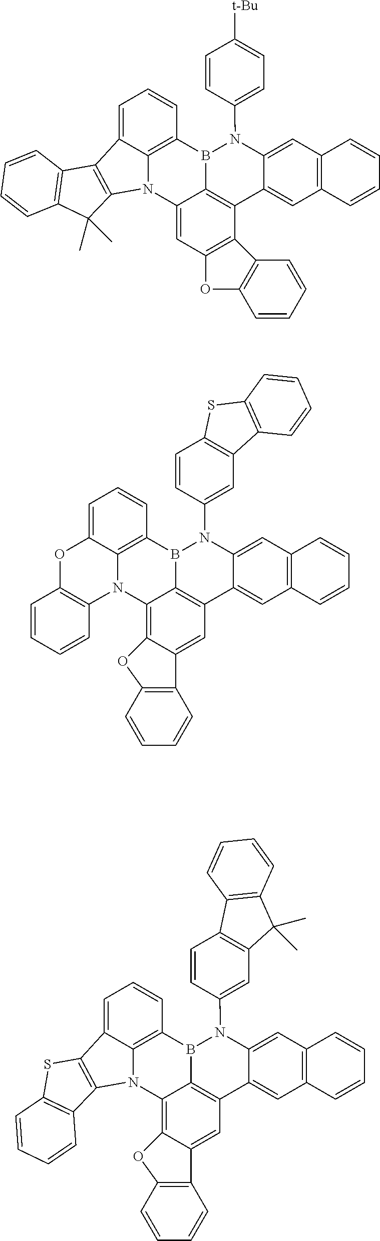 [SMILES: CC(C)(C)c1ccc(N2B3c4c(cc5oc6ccccc6c5c4-c4cc5ccccc5cc42)-n2c4c(c5cccc3c52)-c2ccccc2C4(C)C)cc1 ; c1ccc2c(c1)Oc1cccc3c1N2c1c2c(cc4c1oc1ccccc14)-c1cc4ccccc4cc1N(c1ccc4sc5ccccc5c4c1)B32 ; CC1(C)c2ccccc2-c2ccc(N3B4c5c(cc6c(oc7ccccc76)c5-n5c6c4cccc6c4sc6ccccc6c45)-c4cc5ccccc5cc43)cc21] 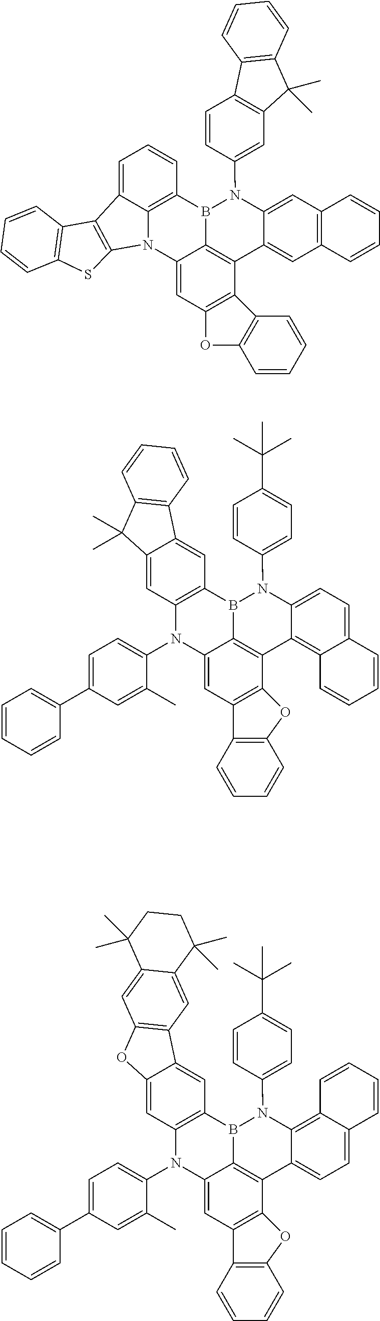 [SMILES: CC1(C)c2ccccc2-c2ccc(N3B4c5c(cc6oc7ccccc7c6c5-c5cc6ccccc6cc53)-n3c5sc6ccccc6c5c5cccc4c53)cc21 ; Cc1cc(-c2ccccc2)ccc1N1c2cc3c(cc2B2c4c1cc1c(oc5ccccc51)c4-c1c(ccc4ccccc14)N2c1ccc(C(C)(C)C)cc1)-c1ccccc1C3(C)C ; Cc1cc(-c2ccccc2)ccc1N1c2cc3oc4cc5c(cc4c3cc2B2c3c1cc1c(oc4ccccc41)c3-c1ccc3ccccc3c1N2c1ccc(C(C)(C)C)cc1)C(C)(C)CCC5(C)C] 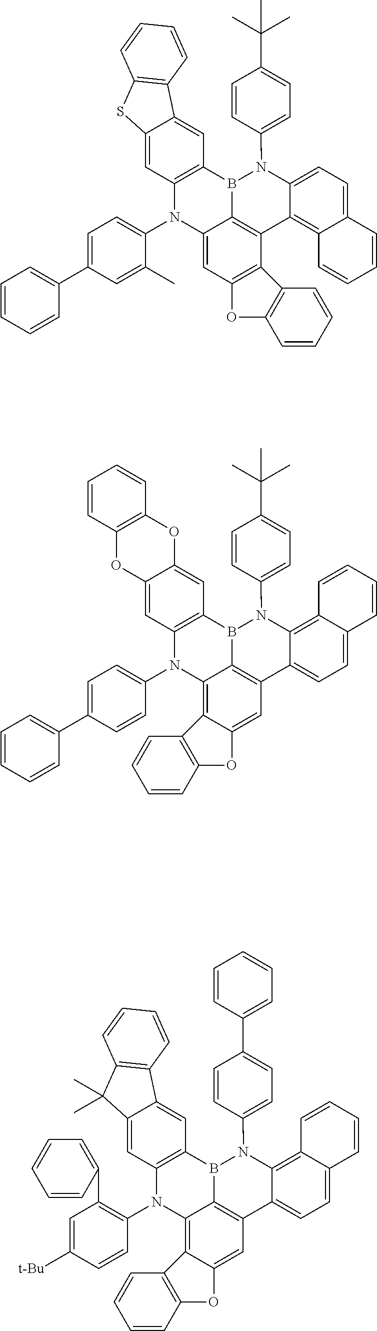 [SMILES: Cc1cc(-c2ccccc2)ccc1N1c2cc3sc4ccccc4c3cc2B2c3c1cc1oc4ccccc4c1c3-c1c(ccc3ccccc13)N2c1ccc(C(C)(C)C)cc1 ; CC(C)(C)c1ccc(N2B3c4cc5c(cc4N(c4ccc(-c6ccccc6)cc4)c4c3c(cc3oc6ccccc6c43)-c3ccc4ccccc4c32)Oc2ccccc2O5)cc1 ; CC(C)(C)c1ccc(N2c3cc4c(cc3B3c5c(cc6oc7ccccc7c6c52)-c2ccc5ccccc5c2N3c2ccc(-c3ccccc3)cc2)-c2ccccc2C4(C)C)c(-c2ccccc2)c1] 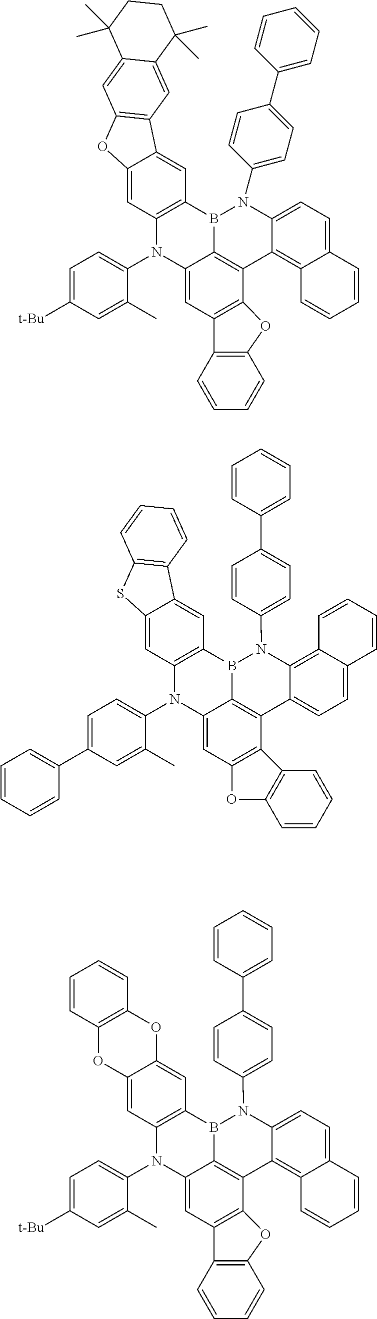 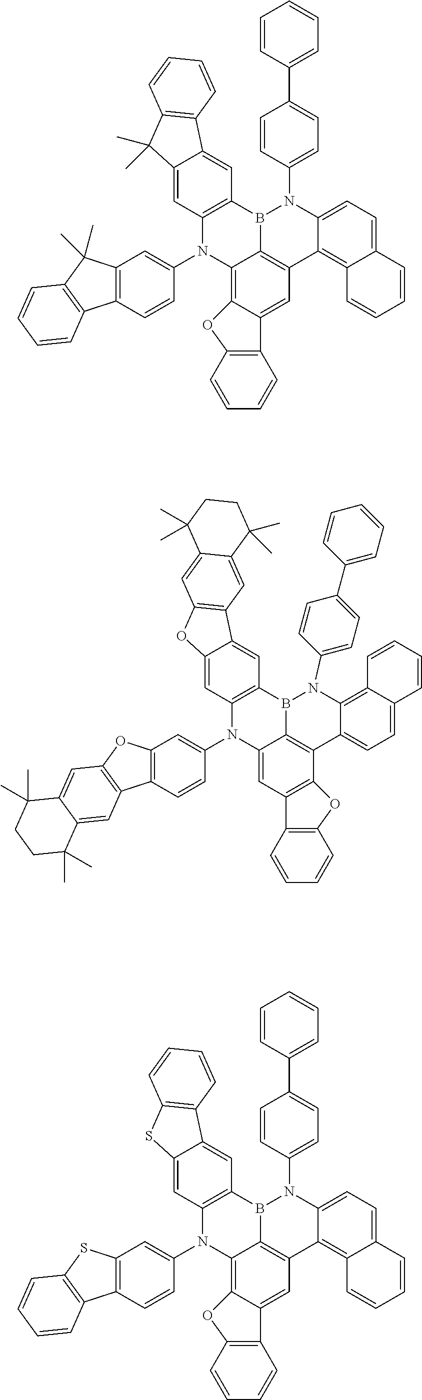 [SMILES: CC1(C)c2ccccc2-c2ccc(N3c4cc5c(cc4B4c6c(cc7c(oc8ccccc87)c63)-c3c(ccc6ccccc36)N4c3ccc(-c4ccccc4)cc3)-c3ccccc3C5(C)C)cc21 ; CC1(C)CCC(C)(C)c2cc3c(cc21)oc1cc(N2c4cc5oc6cc7c(cc6c5cc4B4c5c2cc2c(oc6ccccc62)c5-c2ccc5ccccc5c2N4c2ccc(-c4ccccc4)cc2)C(C)(C)CCC7(C)C)ccc13 ; c1ccc(-c2ccc(N3B4c5cc6c(cc5N(c5ccc7c(c5)sc5ccccc57)c5c4c(cc4c5oc5ccccc54)-c4c3ccc3ccccc43)sc3ccccc36)cc2)cc1] 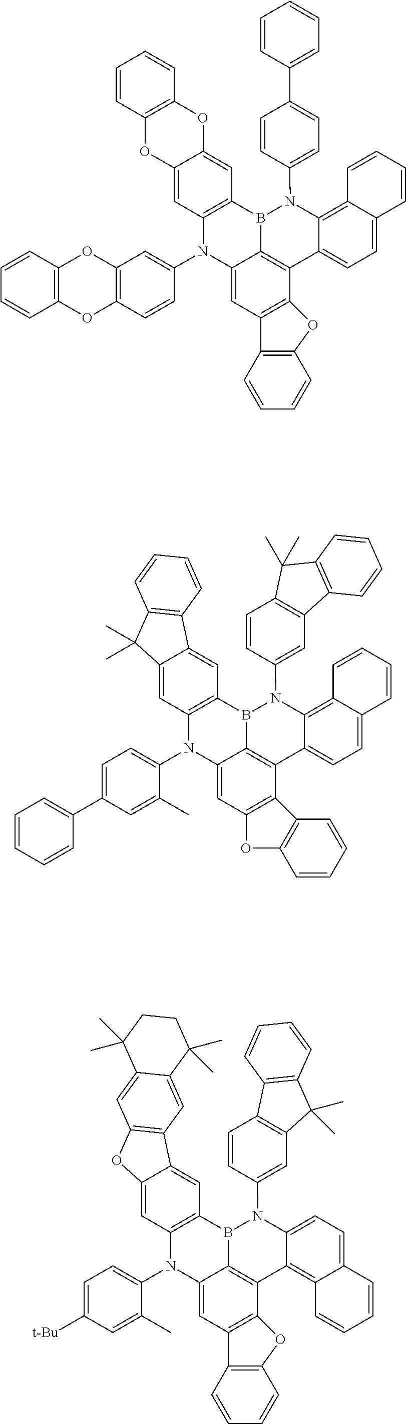 [SMILES: c1ccc(-c2ccc(N3B4c5cc6c(cc5N(c5ccc7c(c5)Oc5ccccc5O7)c5cc7c(oc8ccccc87)c(c54)-c4ccc5ccccc5c43)Oc3ccccc3O6)cc2)cc1 ; Cc1cc(-c2ccccc2)ccc1N1c2cc3c(cc2B2c4c1cc1oc5ccccc5c1c4-c1ccc4ccccc4c1N2c1ccc2c(c1)-c1ccccc1C2(C)C)-c1ccccc1C3(C)C ; Cc1cc(C(C)(C)C)ccc1N1c2cc3oc4cc5c(cc4c3cc2B2c3c1cc1c(oc4ccccc41)c3-c1c(ccc3ccccc13)N2c1ccc2c(c1)C(C)(C)c1ccccc1-2)C(C)(C)CCC5(C)C] 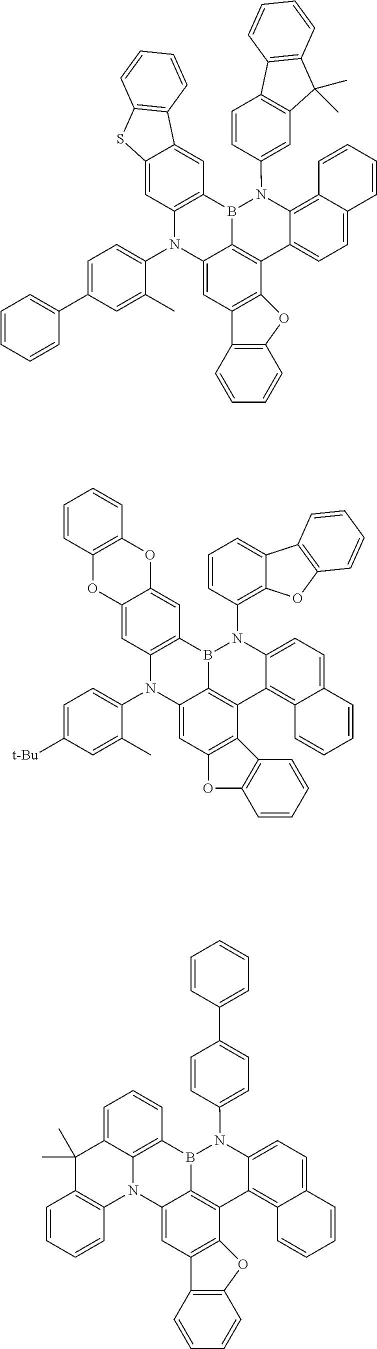 [SMILES: Cc1cc(-c2ccccc2)ccc1N1c2cc3sc4ccccc4c3cc2B2c3c1cc1c(oc4ccccc41)c3-c1ccc3ccccc3c1N2c1ccc2c(c1)C(C)(C)c1ccccc1-2 ; Cc1cc(C(C)(C)C)ccc1N1c2cc3c(cc2B2c4c1cc1oc5ccccc5c1c4-c1c(ccc4ccccc14)N2c1cccc2c1oc1ccccc12)Oc1ccccc1O3 ; CC1(C)c2ccccc2N2c3cc4c(oc5ccccc54)c4c3B(c3cccc1c32)N(c1ccc(-c2ccccc2)cc1)c1ccc2ccccc2c1-4] 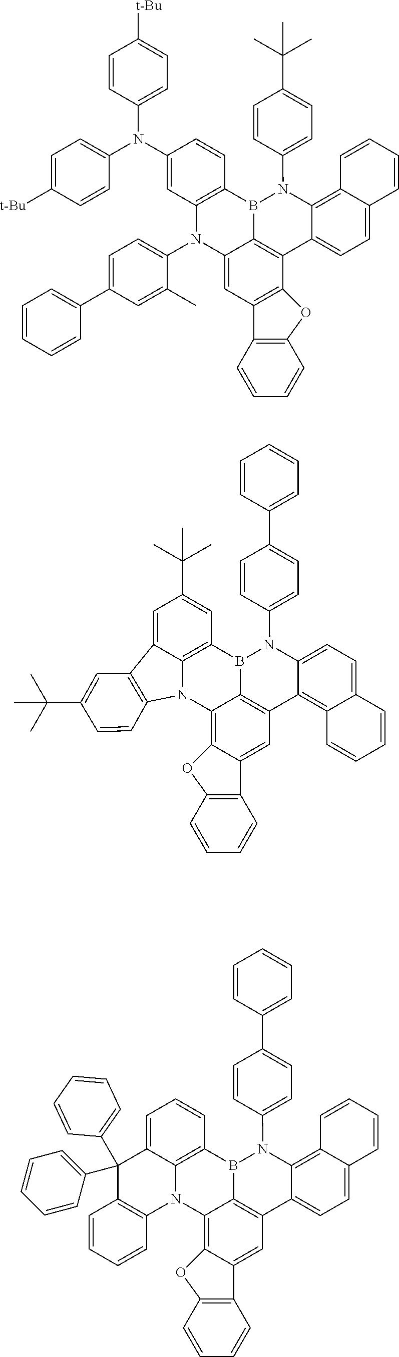 [SMILES: Cc1cc(-c2ccccc2)ccc1N1c2cc(N(c3ccc(C(C)(C)C)cc3)c3ccc(C(C)(C)C)cc3)ccc2B2c3c1cc1c(oc4ccccc41)c3-c1ccc3ccccc3c1N2c1ccc(C(C)(C)C)cc1 ; CC(C)(C)c1ccc2c(c1)c1cc(C(C)(C)C)cc3c1n2-c1c2c(cc4c1oc1ccccc14)-c1c(ccc4ccccc14)N(c1ccc(-c4ccccc4)cc1)B23 ; c1ccc(-c2ccc(N3B4c5cccc6c5N(c5ccccc5C6(c5ccccc5)c5ccccc5)c5c4c(cc4c5oc5ccccc54)-c4ccc5ccccc5c43)cc2)cc1] 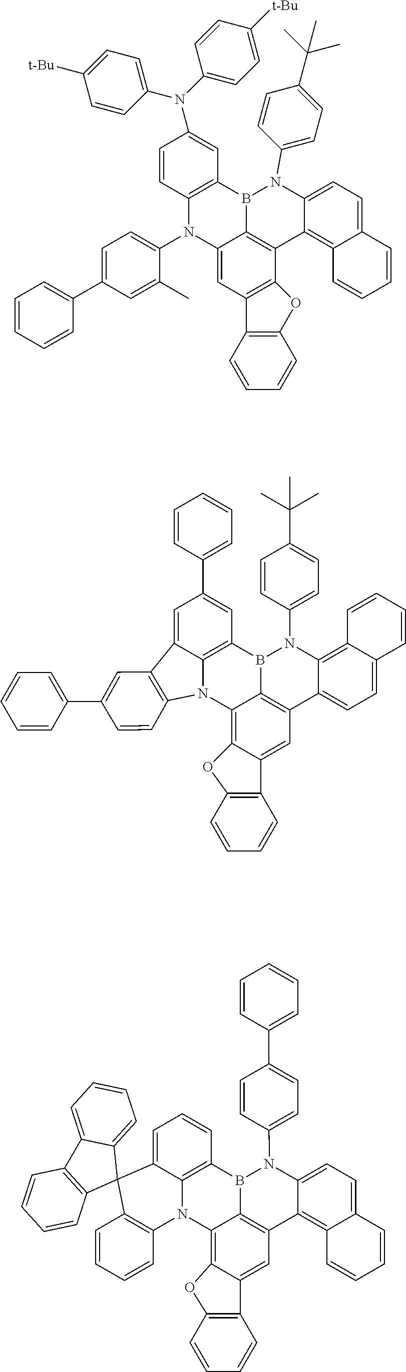 [SMILES: Cc1cc(-c2ccccc2)ccc1N1c2ccc(N(c3ccc(C(C)(C)C)cc3)c3ccc(C(C)(C)C)cc3)cc2B2c3c1cc1c(oc4ccccc41)c3-c1c(ccc3ccccc13)N2c1ccc(C(C)(C)C)cc1 ; CC(C)(C)c1ccc(N2B3c4c(cc5c(oc6ccccc65)c4-n4c5ccc(-c6ccccc6)cc5c5cc(-c6ccccc6)cc3c54)-c3ccc4ccccc4c32)cc1 ; c1ccc(-c2ccc(N3B4c5cccc6c5N(c5ccccc5C65c6ccccc6-c6ccccc65)c5c4c(cc4c5oc5ccccc54)-c4c3ccc3ccccc43)cc2)cc1] 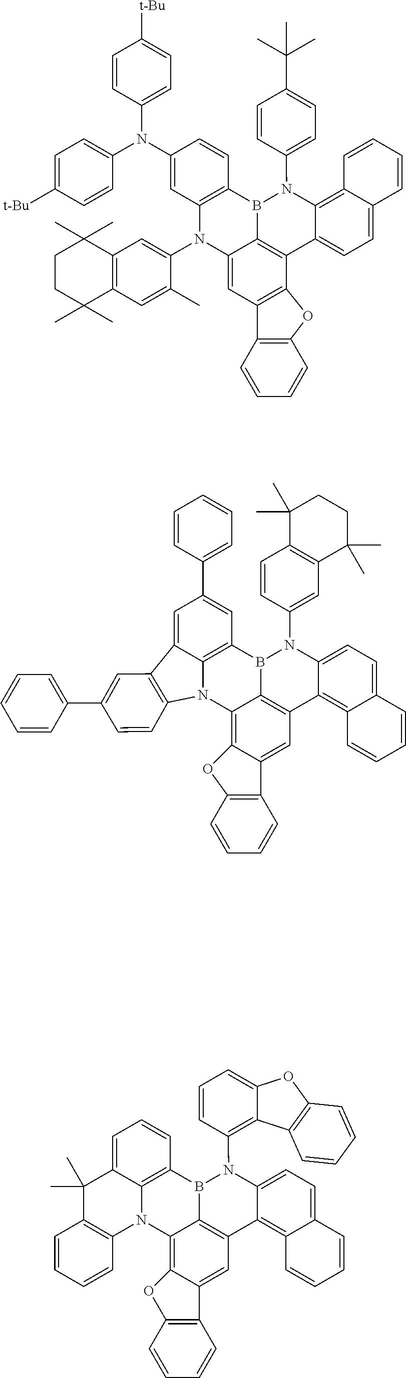 [SMILES: Cc1cc2c(cc1N1c3cc(N(c4ccc(C(C)(C)C)cc4)c4ccc(C(C)(C)C)cc4)ccc3B3c4c1cc1c(oc5ccccc51)c4-c1ccc4ccccc4c1N3c1ccc(C(C)(C)C)cc1)C(C)(C)CCC2(C)C ; CC1(C)CCC(C)(C)c2cc(N3B4c5c(cc6c(oc7ccccc76)c5-n5c6ccc(-c7ccccc7)cc6c6cc(-c7ccccc7)cc4c65)-c4c3ccc3ccccc43)ccc21 ; CC1(C)c2ccccc2N2c3c(cccc31)B1c3c(cc4c(oc5ccccc54)c32)-c2c(ccc3ccccc23)N1c1cccc2oc3ccccc3c12] 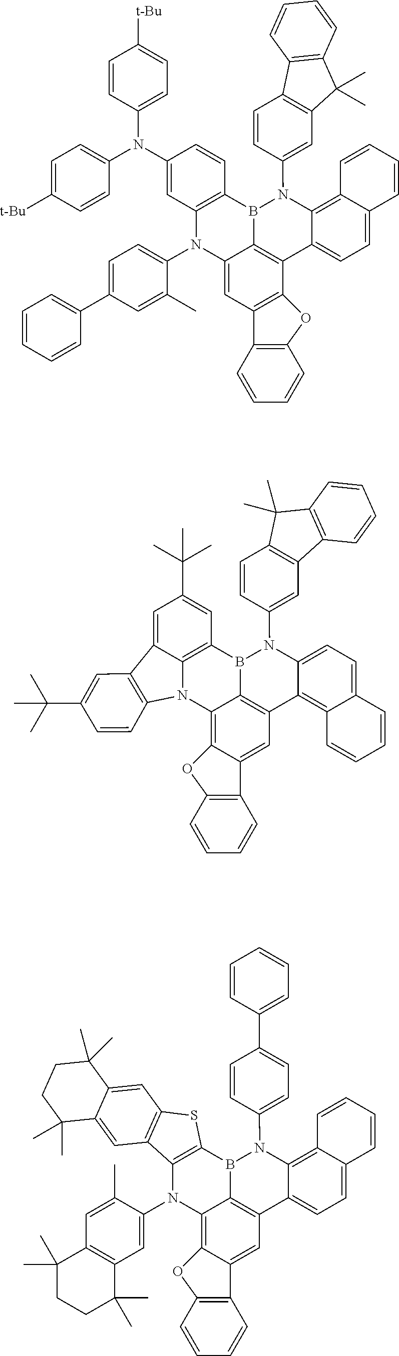 [SMILES: Cc1cc(-c2ccccc2)ccc1N1c2cc(N(c3ccc(C(C)(C)C)cc3)c3ccc(C(C)(C)C)cc3)ccc2B2c3c1cc1c(oc4ccccc41)c3-c1ccc3ccccc3c1N2c1ccc2c(c1)C(C)(C)c1ccccc1-2 ; CC(C)(C)c1ccc2c(c1)c1cc(C(C)(C)C)cc3c1n2-c1c2c(cc4c1oc1ccccc14)-c1c(ccc4ccccc14)N(c1ccc4c(c1)-c1ccccc1C4(C)C)B23 ; Cc1cc2c(cc1N1c3c(sc4cc5c(cc34)C(C)(C)CCC5(C)C)B3c4c(cc5c(oc6ccccc65)c41)-c1ccc4ccccc4c1N3c1ccc(-c3ccccc3)cc1)C(C)(C)CCC2(C)C] 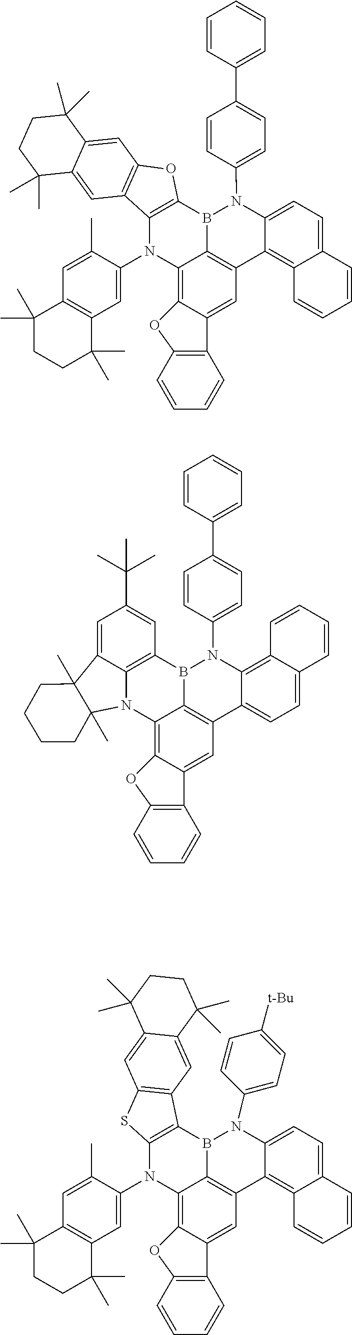 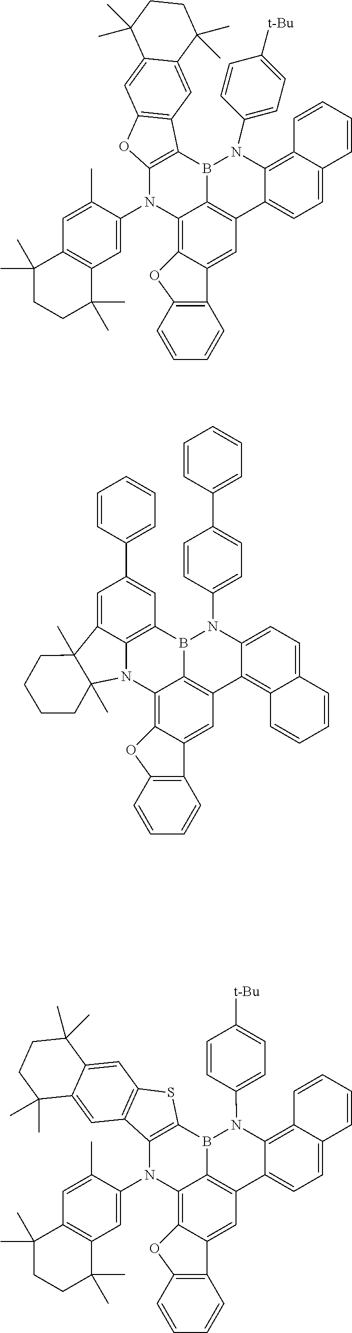 [SMILES: Cc1cc2c(cc1N1c3oc4cc5c(cc4c3B3c4c(cc6c(oc7ccccc76)c41)-c1ccc4ccccc4c1N3c1ccc(C(C)(C)C)cc1)C(C)(C)CCC5(C)C)C(C)(C)CCC2(C)C ; CC12CCCCC1(C)N1c3c(cc(-c4ccccc4)cc32)B2c3c(cc4c(oc5ccccc54)c31)-c1c(ccc3ccccc13)N2c1ccc(-c2ccccc2)cc1 ; Cc1cc2c(cc1N1c3c(sc4cc5c(cc34)C(C)(C)CCC5(C)C)B3c4c(cc5c(oc6ccccc65)c41)-c1ccc4ccccc4c1N3c1ccc(C(C)(C)C)cc1)C(C)(C)CCC2(C)C] 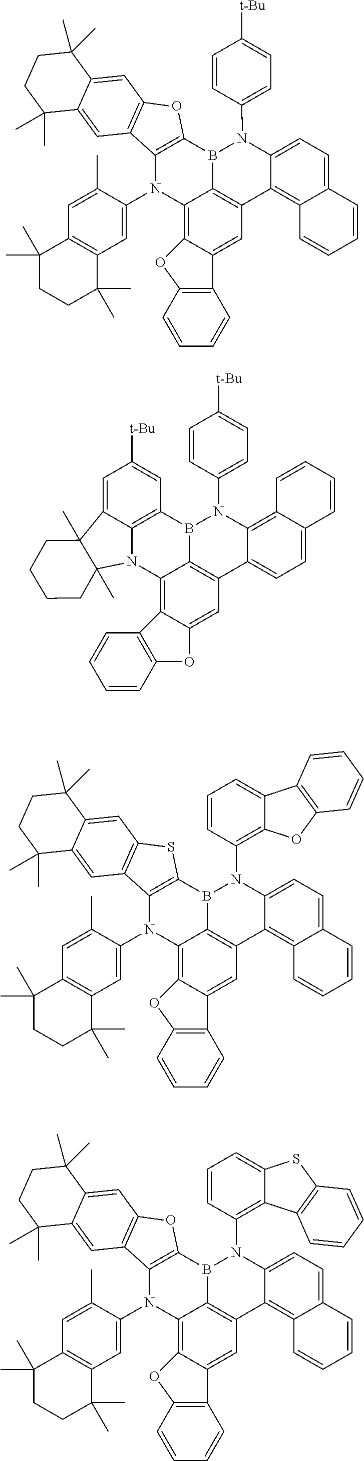 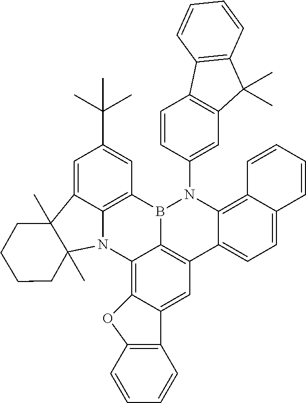 [SMILES: CC(C)(C)c1cc2c3c(c1)C1(C)CCCCC1(C)N3c1c3c(cc4c1oc1ccccc14)-c1ccc4ccccc4c1N(c1ccc4c(c1)C(C)(C)c1ccccc1-4)B23] 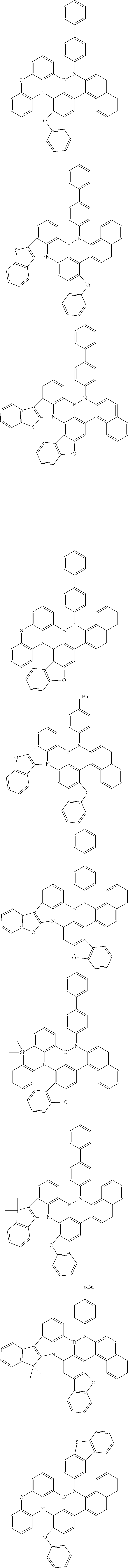 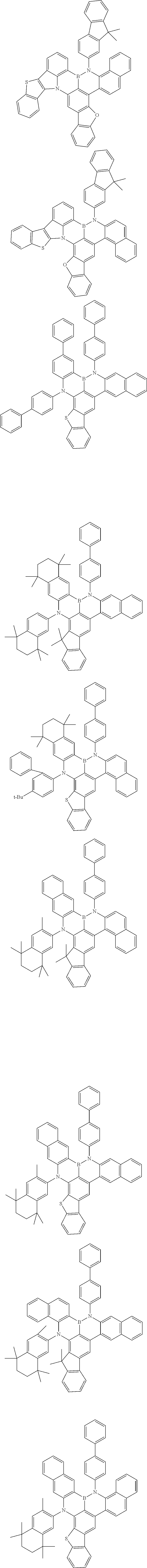 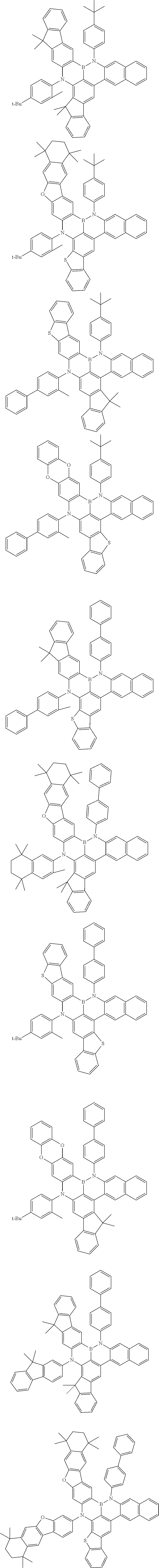 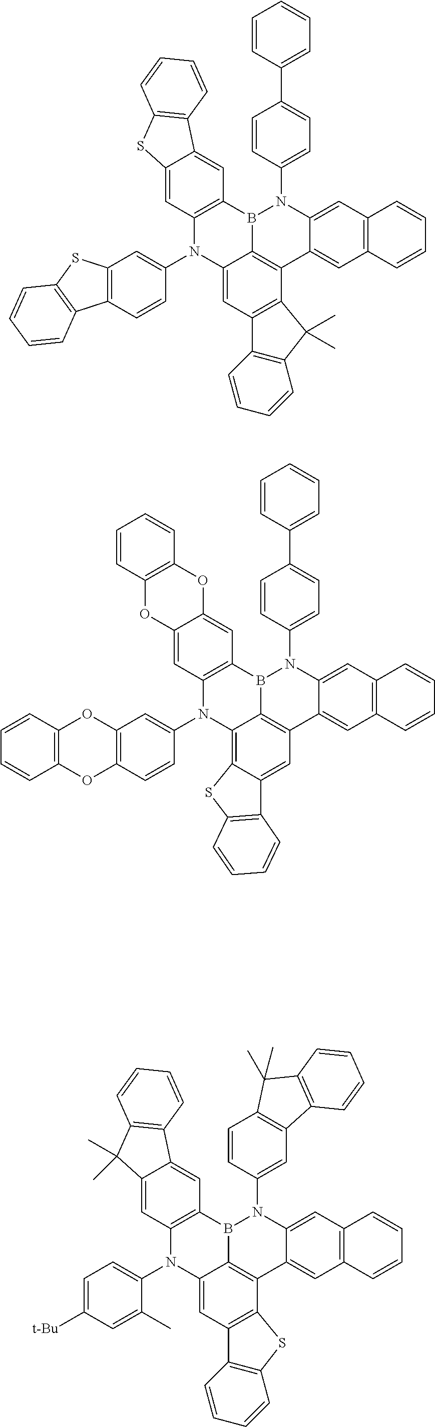 [SMILES: CC1(C)c2ccccc2-c2cc3c4c(c21)-c1cc2ccccc2cc1N(c1ccc(-c2ccccc2)cc1)B4c1cc2c(cc1N3c1ccc3c(c1)sc1ccccc13)sc1ccccc12 ; c1ccc(-c2ccc(N3B4c5cc6c(cc5N(c5ccc7c(c5)Oc5ccccc5O7)c5c4c(cc4c5sc5ccccc54)-c4cc5ccccc5cc43)Oc3ccccc3O6)cc2)cc1 ; Cc1cc(C(C)(C)C)ccc1N1c2cc3c(cc2B2c4c1cc1c(sc5ccccc51)c4-c1cc4ccccc4cc1N2c1ccc2c(c1)-c1ccccc1C2(C)C)-c1ccccc1C3(C)C] 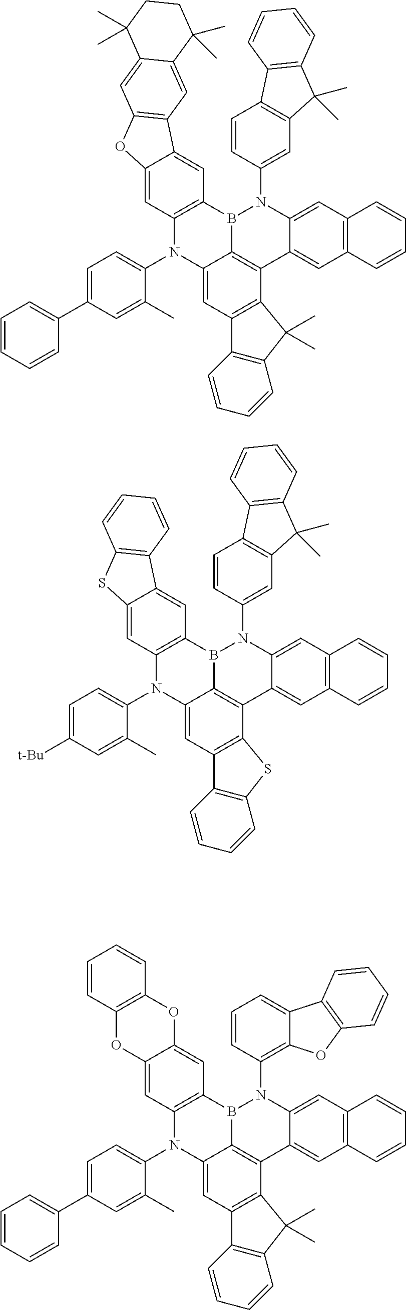 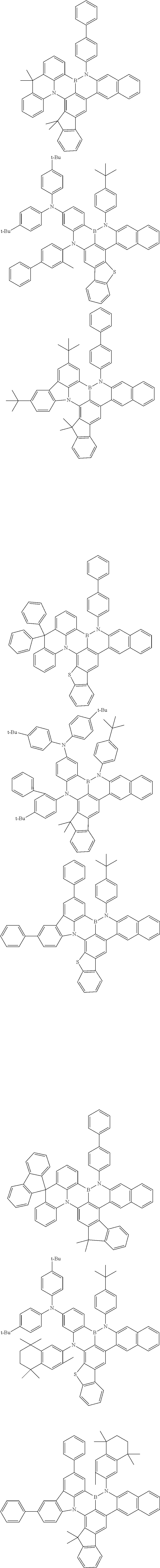 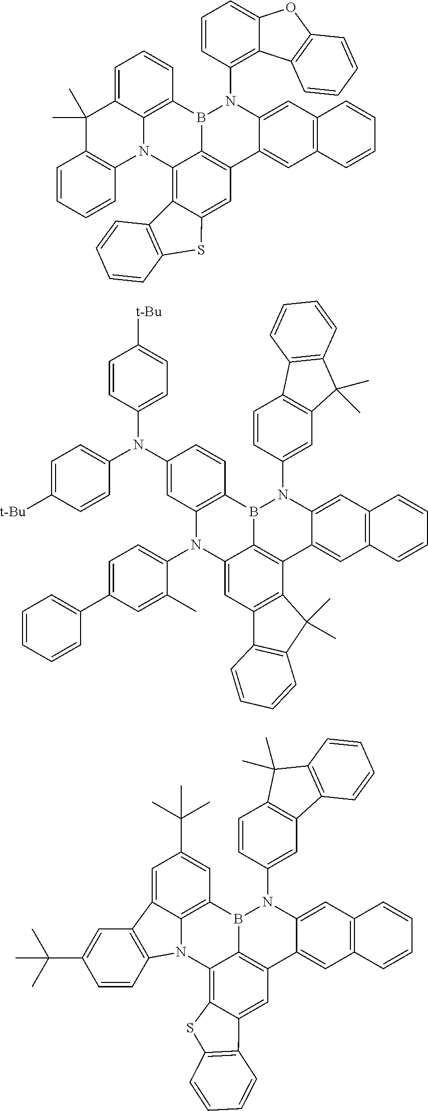 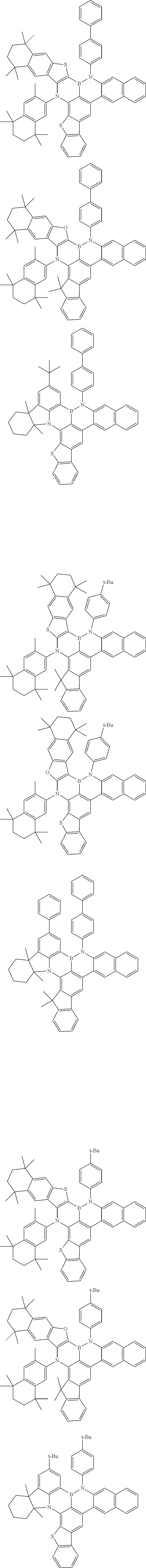 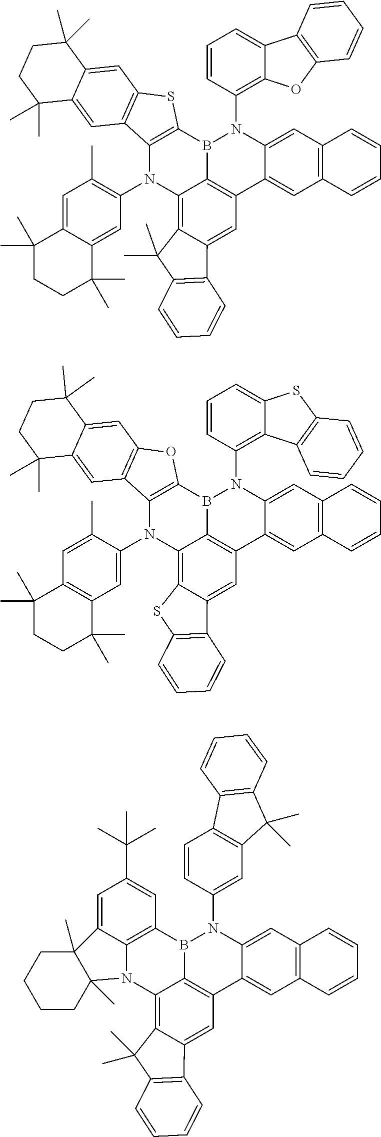 [SMILES: Cc1cc2c(cc1N1c3c4c(cc5c3C(C)(C)c3ccccc3-5)-c3cc5ccccc5cc3N(c3cccc5c3oc3ccccc35)B4c3sc4cc5c(cc4c31)C(C)(C)CCC5(C)C)C(C)(C)CCC2(C)C ; Cc1cc2c(cc1N1c3c(oc4cc5c(cc34)C(C)(C)CCC5(C)C)B3c4c(cc5c(sc6ccccc65)c41)-c1cc4ccccc4cc1N3c1cccc3sc4ccccc4c13)C(C)(C)CCC2(C)C ; CC(C)(C)c1cc2c3c(c1)C1(C)CCCCC1(C)N3c1c3c(cc4c1C(C)(C)c1ccccc1-4)-c1cc4ccccc4cc1N(c1ccc4c(c1)C(C)(C)c1ccccc1-4)B23] 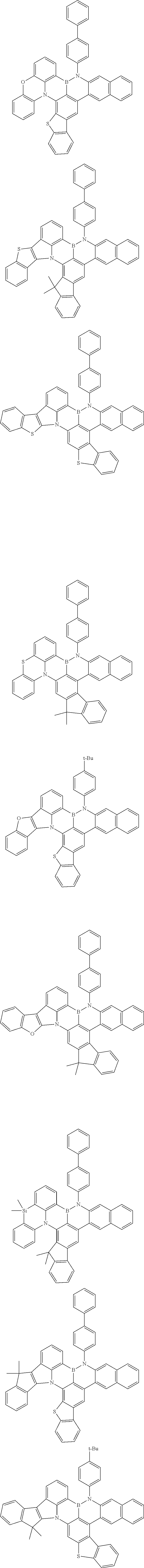 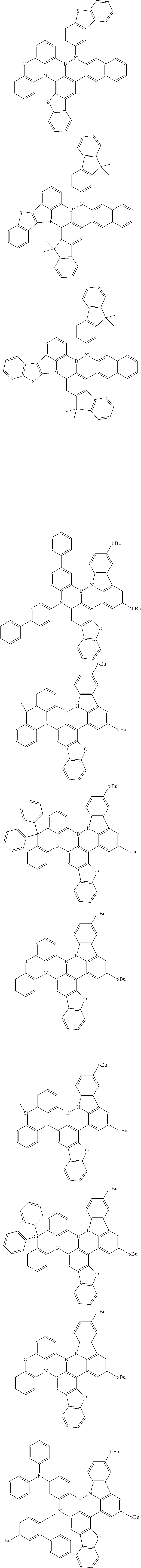 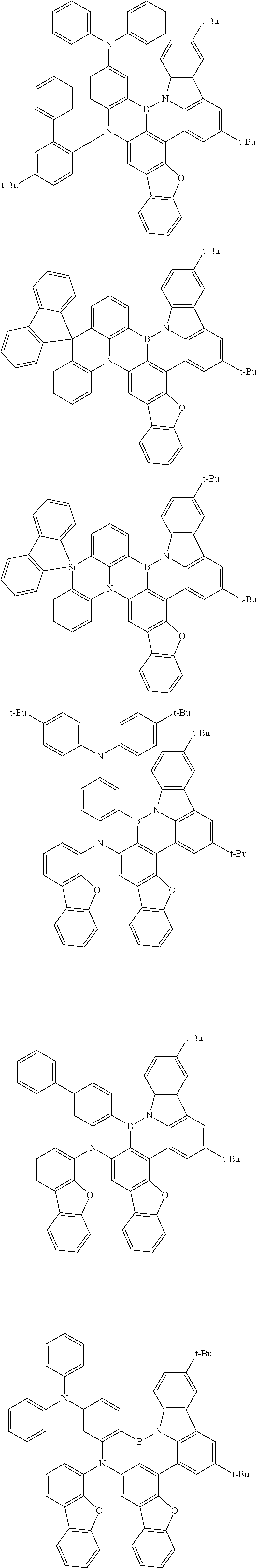 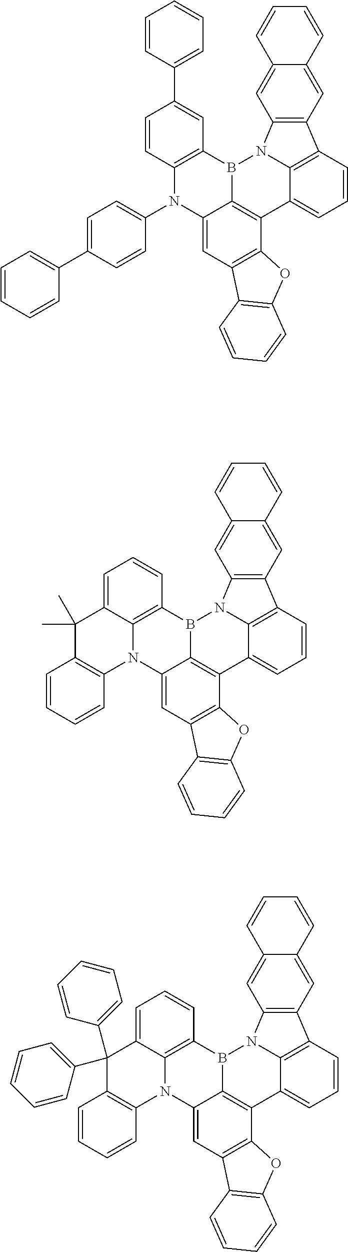 [SMILES: c1ccc(-c2ccc(N3c4ccc(-c5ccccc5)cc4B4c5c3cc3c(oc6ccccc63)c5-c3cccc5c6cc7ccccc7cc6n4c35)cc2)cc1 ; CC1(C)c2ccccc2N2c3cc4c(oc5ccccc54)c4c3B(c3cccc1c32)n1c2cc3ccccc3cc2c2cccc-4c21 ; c1ccc(C2(c3ccccc3)c3ccccc3N3c4cc5c(oc6ccccc65)c5c4B(c4cccc2c43)n2c3cc4ccccc4cc3c3cccc-5c32)cc1] 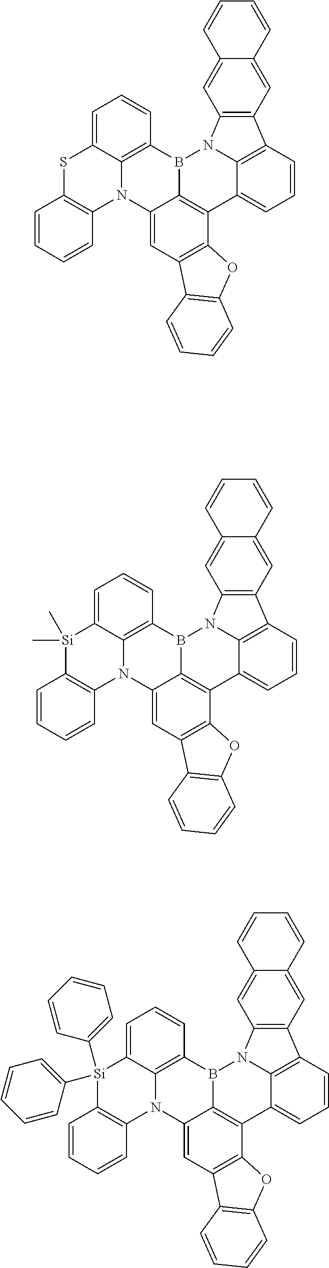 [SMILES: c1ccc2c(c1)Sc1cccc3c1N2c1cc2c(oc4ccccc42)c2c1B3n1c3cc4ccccc4cc3c3cccc-2c31 ; C[Si]1(C)c2ccccc2N2c3cc4c(oc5ccccc54)c4c3B(c3cccc1c32)n1c2cc3ccccc3cc2c2cccc-4c21 ; c1ccc([Si]2(c3ccccc3)c3ccccc3N3c4cc5c(oc6ccccc65)c5c4B(c4cccc2c43)n2c3cc4ccccc4cc3c3cccc-5c32)cc1] 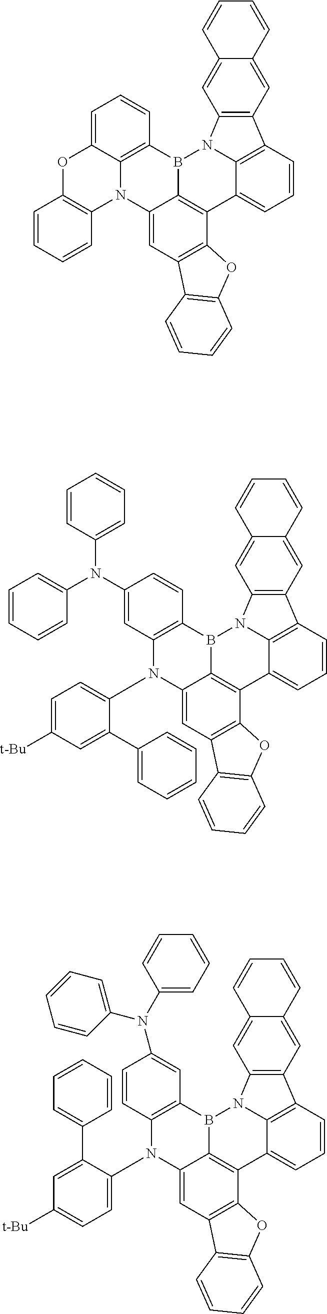 [SMILES: c1ccc2c(c1)Oc1cccc3c1N2c1cc2c(oc4ccccc42)c2c1B3n1c3cc4ccccc4cc3c3cccc-2c31 ; CC(C)(C)c1ccc(N2c3cc(N(c4ccccc4)c4ccccc4)ccc3B3c4c2cc2c(oc5ccccc52)c4-c2cccc4c5cc6ccccc6cc5n3c24)c(-c2ccccc2)c1 ; CC(C)(C)c1ccc(N2c3ccc(N(c4ccccc4)c4ccccc4)cc3B3c4c2cc2c(oc5ccccc52)c4-c2cccc4c5cc6ccccc6cc5n3c24)c(-c2ccccc2)c1] 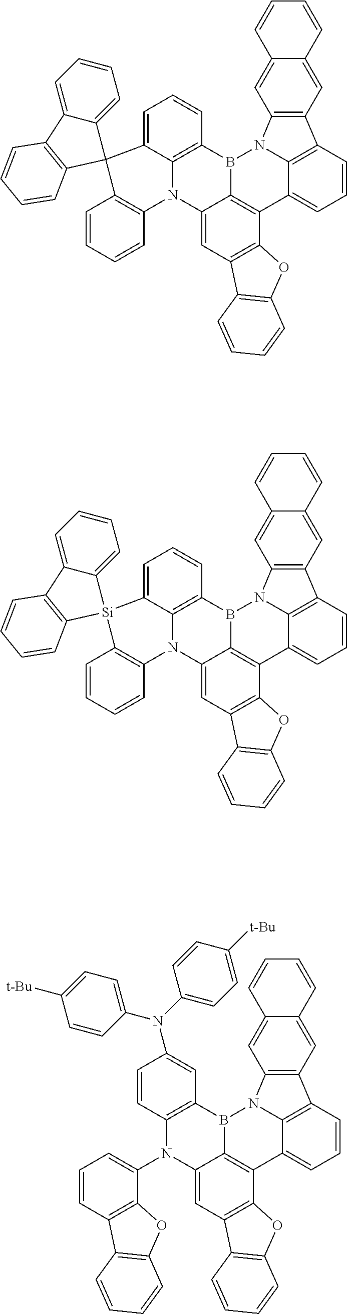 [SMILES: c1ccc2c(c1)-c1ccccc1C21c2ccccc2N2c3cc4c(oc5ccccc54)c4c3B(c3cccc1c32)n1c2cc3ccccc3cc2c2cccc-4c21 ; c1ccc2c(c1)-c1ccccc1[Si]21c2ccccc2N2c3cc4c(oc5ccccc54)c4c3B(c3cccc1c32)n1c2cc3ccccc3cc2c2cccc-4c21 ; CC(C)(C)c1ccc(N(c2ccc(C(C)(C)C)cc2)c2ccc3c(c2)B2c4c(cc5c(oc6ccccc65)c4-c4cccc5c6cc7ccccc7cc6n2c45)N3c2cccc3c2oc2ccccc23)cc1] 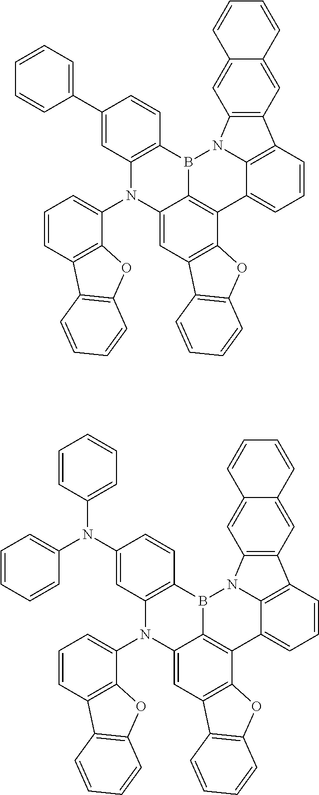 [SMILES: c1ccc(-c2ccc3c(c2)N(c2cccc4c2oc2ccccc24)c2cc4c(oc5ccccc54)c4c2B3n2c3cc5ccccc5cc3c3cccc-4c32)cc1 ; c1ccc(N(c2ccccc2)c2ccc3c(c2)N(c2cccc4c2oc2ccccc24)c2cc4c(oc5ccccc54)c4c2B3n2c3cc5ccccc5cc3c3cccc-4c32)cc1] 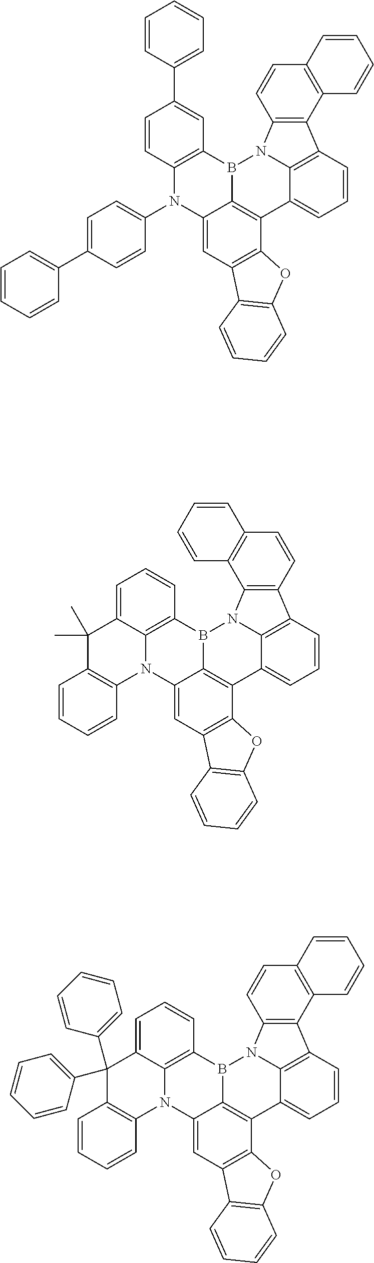 [SMILES: c1ccc(-c2ccc(N3c4ccc(-c5ccccc5)cc4B4c5c3cc3c(oc6ccccc63)c5-c3cccc5c6c7ccccc7ccc6n4c35)cc2)cc1 ; CC1(C)c2ccccc2N2c3cc4c(oc5ccccc54)c4c3B(c3cccc1c32)n1c2c-4cccc2c2ccc3ccccc3c21 ; c1ccc(C2(c3ccccc3)c3ccccc3N3c4cc5c(oc6ccccc65)c5c4B(c4cccc2c43)n2c3ccc4ccccc4c3c3cccc-5c32)cc1] 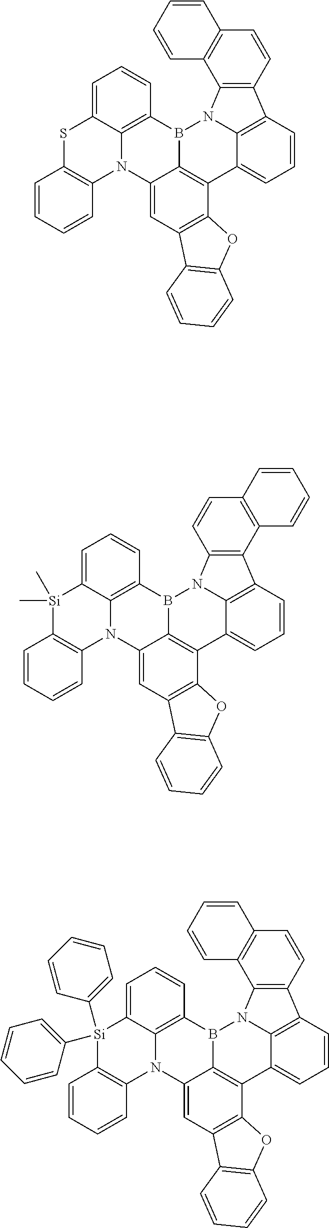 [SMILES: c1ccc2c(c1)Sc1cccc3c1N2c1cc2c(oc4ccccc42)c2c1B3n1c3c-2cccc3c2ccc3ccccc3c21 ; C[Si]1(C)c2ccccc2N2c3cc4c(oc5ccccc54)c4c3B(c3cccc1c32)n1c2ccc3ccccc3c2c2cccc-4c21 ; c1ccc([Si]2(c3ccccc3)c3ccccc3N3c4cc5c(oc6ccccc65)c5c4B(c4cccc2c43)n2c3c-5cccc3c3ccc4ccccc4c32)cc1] 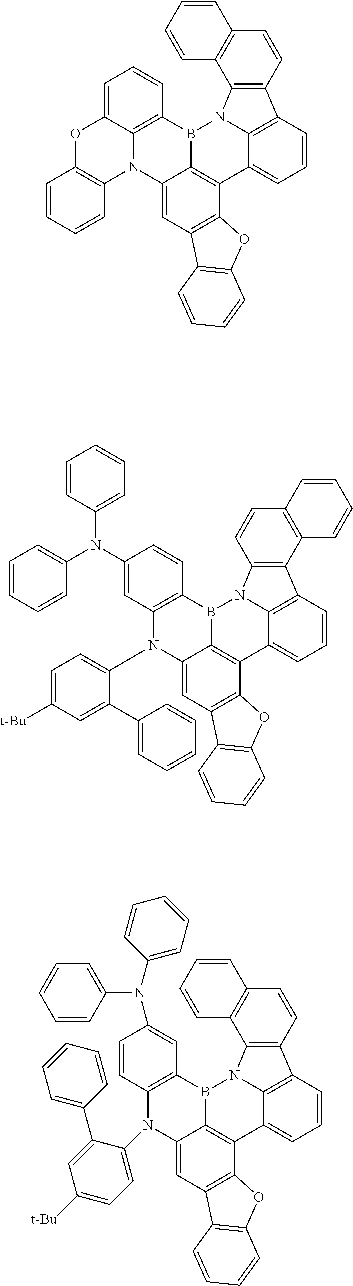 [SMILES: c1ccc2c(c1)Oc1cccc3c1N2c1cc2c(oc4ccccc42)c2c1B3n1c3c-2cccc3c2ccc3ccccc3c21 ; CC(C)(C)c1ccc(N2c3cc(N(c4ccccc4)c4ccccc4)ccc3B3c4c2cc2c(oc5ccccc52)c4-c2cccc4c5c6ccccc6ccc5n3c24)c(-c2ccccc2)c1 ; CC(C)(C)c1ccc(N2c3ccc(N(c4ccccc4)c4ccccc4)cc3B3c4c2cc2c(oc5ccccc52)c4-c2cccc4c5ccc6ccccc6c5n3c24)c(-c2ccccc2)c1] 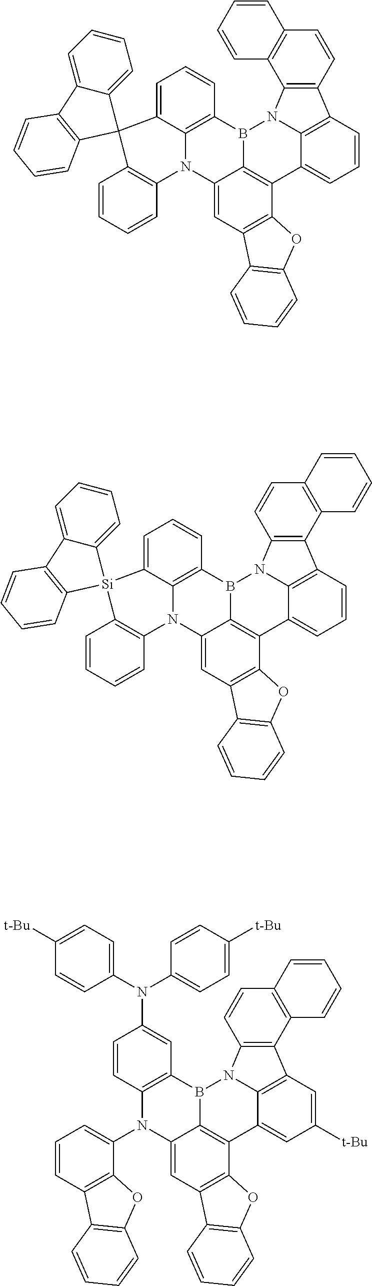 [SMILES: c1ccc2c(c1)-c1ccccc1C21c2ccccc2N2c3cc4c(oc5ccccc54)c4c3B(c3cccc1c32)n1c2c-4cccc2c2ccc3ccccc3c21 ; c1ccc2c(c1)-c1ccccc1[Si]21c2ccccc2N2c3cc4c(oc5ccccc54)c4c3B(c3cccc1c32)n1c2ccc3ccccc3c2c2cccc-4c21 ; CC(C)(C)c1ccc(N(c2ccc(C(C)(C)C)cc2)c2ccc3c(c2)B2c4c(cc5c(oc6ccccc65)c4-c4cc(C(C)(C)C)cc5c6c7ccccc7ccc6n2c45)N3c2cccc3c2oc2ccccc23)cc1] 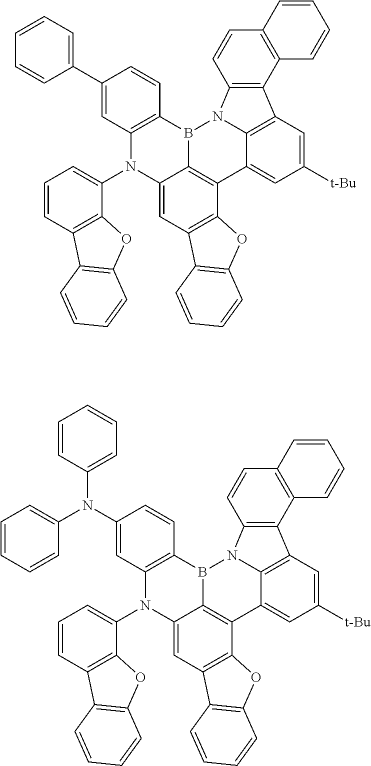 [SMILES: CC(C)(C)c1cc2c3c(c1)c1c4ccccc4ccc1n3B1c3ccc(-c4ccccc4)cc3N(c3cccc4c3oc3ccccc34)c3cc4c(oc5ccccc54)c-2c31 ; CC(C)(C)c1cc2c3c(c1)c1c4ccccc4ccc1n3B1c3ccc(N(c4ccccc4)c4ccccc4)cc3N(c3cccc4c3oc3ccccc34)c3cc4c(oc5ccccc54)c-2c31] 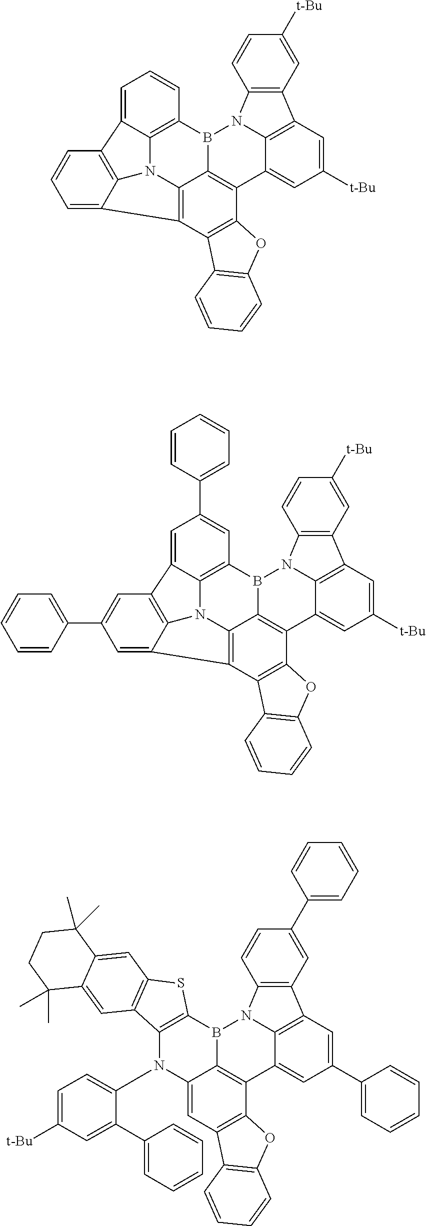 [SMILES: CC(C)(C)c1ccc2c(c1)c1cc(C(C)(C)C)cc3c1n2B1c2cccc4c5cccc6c7c8c(oc9ccccc98)c-3c1c7n(c24)c56 ; CC(C)(C)c1ccc2c(c1)c1cc(C(C)(C)C)cc3c1n2B1c2cc(-c4ccccc4)cc4c5cc(-c6ccccc6)cc6c7c8c(oc9ccccc98)c-3c1c7n(c24)c56 ; CC(C)(C)c1ccc(N2c3cc4c(oc5ccccc54)c4c3B(c3sc5cc6c(cc5c32)C(C)(C)CCC6(C)C)n2c3ccc(-c5ccccc5)cc3c3cc(-c5ccccc5)cc-4c32)c(-c2ccccc2)c1] 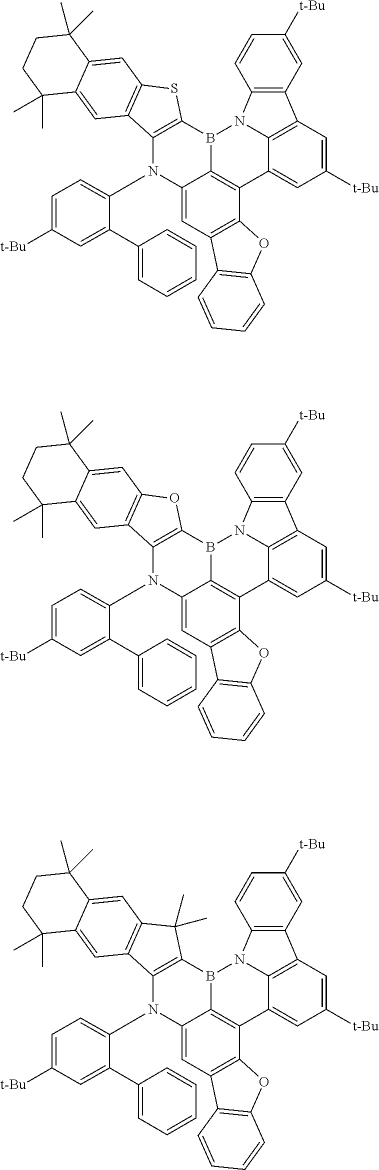 [SMILES: CC(C)(C)c1ccc(N2c3cc4c(oc5ccccc54)c4c3B(c3sc5cc6c(cc5c32)C(C)(C)CCC6(C)C)n2c3ccc(C(C)(C)C)cc3c3cc(C(C)(C)C)cc-4c32)c(-c2ccccc2)c1 ; CC(C)(C)c1ccc(N2c3cc4c(oc5ccccc54)c4c3B(c3oc5cc6c(cc5c32)C(C)(C)CCC6(C)C)n2c3ccc(C(C)(C)C)cc3c3cc(C(C)(C)C)cc-4c32)c(-c2ccccc2)c1 ; CC(C)(C)c1ccc(N2C3=C(B4c5c2cc2c(oc6ccccc62)c5-c2cc(C(C)(C)C)cc5c6cc(C(C)(C)C)ccc6n4c25)C(C)(C)c2cc4c(cc23)C(C)(C)CCC4(C)C)c(-c2ccccc2)c1] 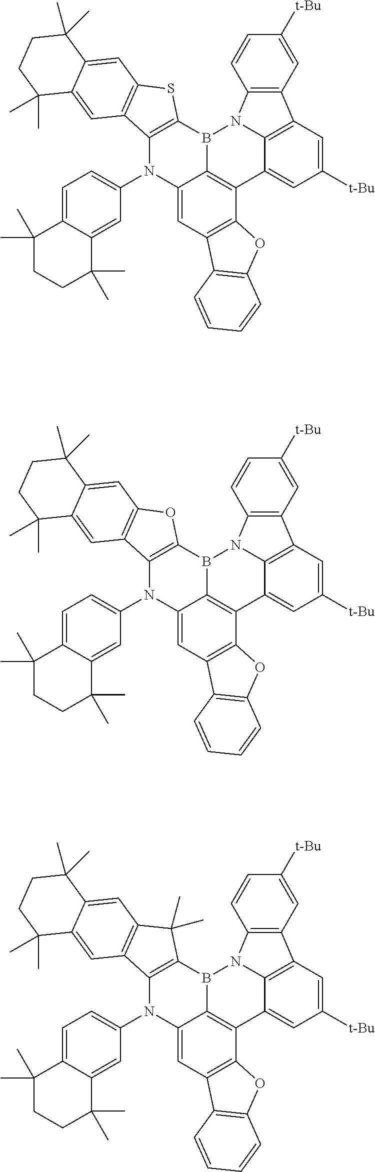 [SMILES: CC(C)(C)c1ccc2c(c1)c1cc(C(C)(C)C)cc3c1n2B1c2sc4cc5c(cc4c2N(c2ccc4c(c2)C(C)(C)CCC4(C)C)c2cc4c(oc6ccccc64)c-3c21)C(C)(C)CCC5(C)C ; CC(C)(C)c1ccc2c(c1)c1cc(C(C)(C)C)cc3c1n2B1c2oc4cc5c(cc4c2N(c2ccc4c(c2)C(C)(C)CCC4(C)C)c2cc4c(oc6ccccc64)c-3c21)C(C)(C)CCC5(C)C ; CC(C)(C)c1ccc2c(c1)c1cc(C(C)(C)C)cc3c1n2B1C2=C(c4cc5c(cc4C2(C)C)C(C)(C)CCC5(C)C)N(c2ccc4c(c2)C(C)(C)CCC4(C)C)c2cc4c(oc5ccccc54)c-3c21] 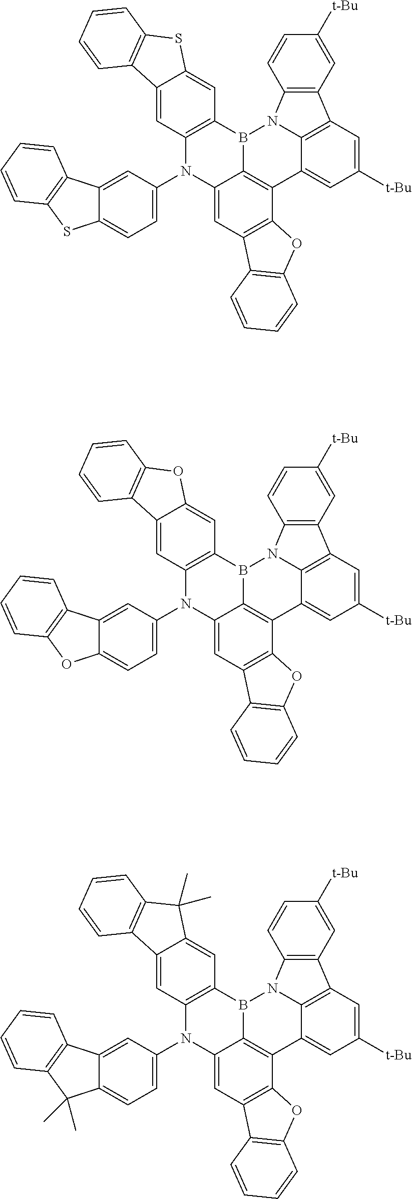 [SMILES: CC(C)(C)c1ccc2c(c1)c1cc(C(C)(C)C)cc3c1n2B1c2cc4sc5ccccc5c4cc2N(c2ccc4sc5ccccc5c4c2)c2cc4c(oc5ccccc54)c-3c21 ; CC(C)(C)c1ccc2c(c1)c1cc(C(C)(C)C)cc3c1n2B1c2cc4oc5ccccc5c4cc2N(c2ccc4oc5ccccc5c4c2)c2cc4c(oc5ccccc54)c-3c21 ; CC(C)(C)c1ccc2c(c1)c1cc(C(C)(C)C)cc3c1n2B1c2cc4c(cc2N(c2ccc5c(c2)-c2ccccc2C5(C)C)c2cc5c(oc6ccccc65)c-3c21)-c1ccccc1C4(C)C] 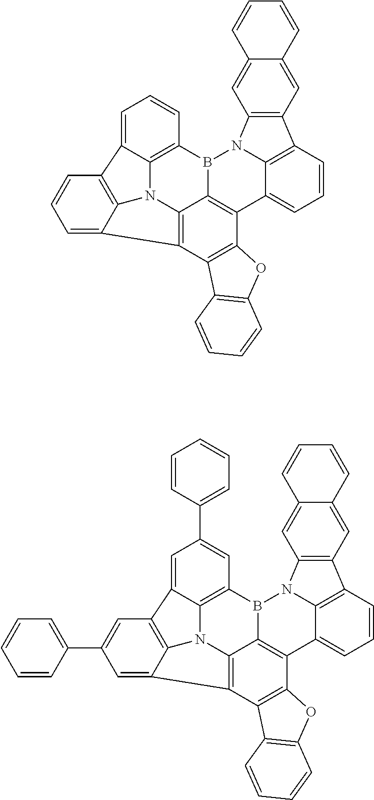 [SMILES: c1ccc2cc3c(cc2c1)c1cccc2c1n3B1c3cccc4c5cccc6c7c8c(oc9ccccc98)c-2c1c7n(c34)c56 ; c1ccc(-c2cc3c4c(c2)c2cc(-c5ccccc5)cc5c6c7c(oc8ccccc87)c7c(c6n4c25)B3n2c3cc4ccccc4cc3c3cccc-7c32)cc1] 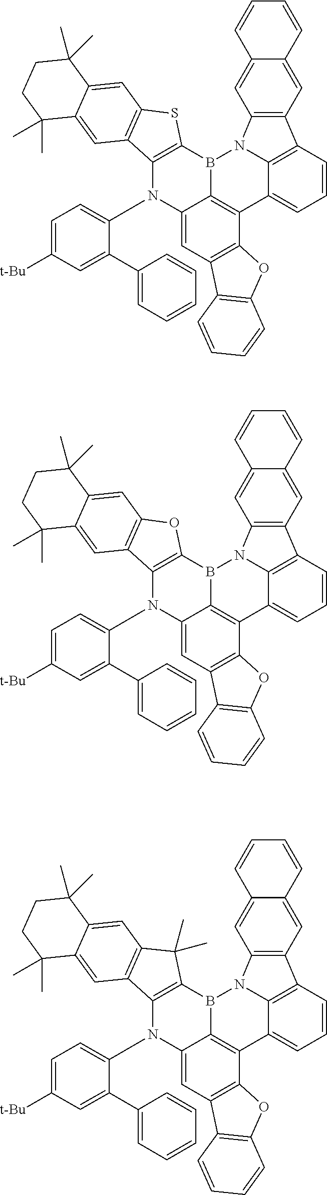 [SMILES: CC(C)(C)c1ccc(N2c3cc4c(oc5ccccc54)c4c3B(c3sc5cc6c(cc5c32)C(C)(C)CCC6(C)C)n2c3cc5ccccc5cc3c3cccc-4c32)c(-c2ccccc2)c1 ; CC(C)(C)c1ccc(N2c3cc4c(oc5ccccc54)c4c3B(c3oc5cc6c(cc5c32)C(C)(C)CCC6(C)C)n2c3cc5ccccc5cc3c3cccc-4c32)c(-c2ccccc2)c1 ; CC(C)(C)c1ccc(N2C3=C(B4c5c2cc2c(oc6ccccc62)c5-c2cccc5c6cc7ccccc7cc6n4c25)C(C)(C)c2cc4c(cc23)C(C)(C)CCC4(C)C)c(-c2ccccc2)c1] 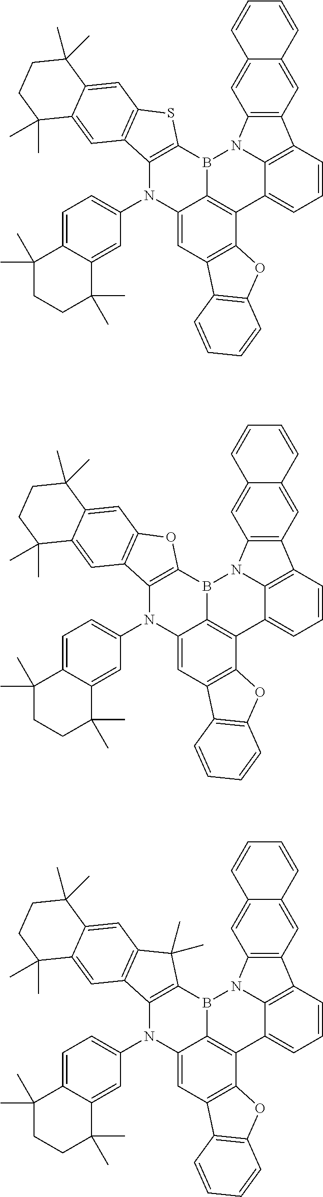 [SMILES: CC1(C)CCC(C)(C)c2cc(N3c4cc5c(oc6ccccc65)c5c4B(c4sc6cc7c(cc6c43)C(C)(C)CCC7(C)C)n3c4cc6ccccc6cc4c4cccc-5c43)ccc21 ; CC1(C)CCC(C)(C)c2cc(N3c4cc5c(oc6ccccc65)c5c4B(c4oc6cc7c(cc6c43)C(C)(C)CCC7(C)C)n3c4cc6ccccc6cc4c4cccc-5c43)ccc21 ; CC1(C)CCC(C)(C)c2cc(N3C4=C(B5c6c3cc3c(oc7ccccc73)c6-c3cccc6c7cc8ccccc8cc7n5c36)C(C)(C)c3cc5c(cc34)C(C)(C)CCC5(C)C)ccc21] 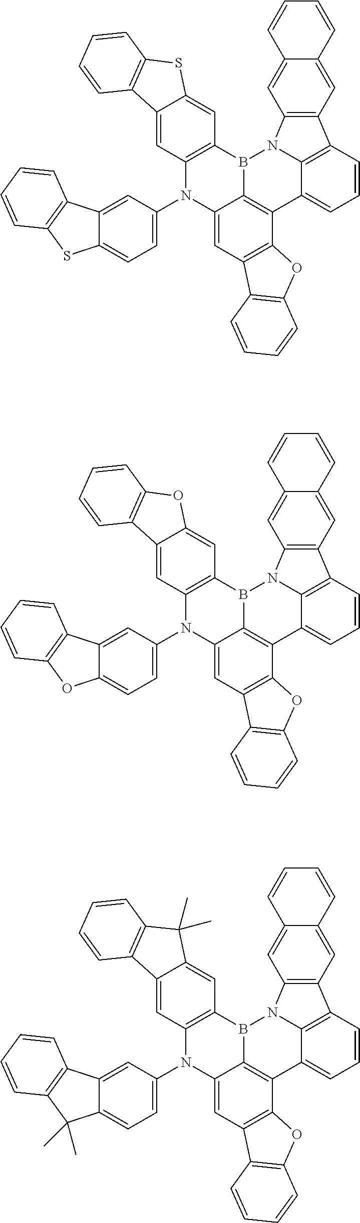 [SMILES: c1ccc2cc3c(cc2c1)c1cccc2c1n3B1c3cc4sc5ccccc5c4cc3N(c3ccc4sc5ccccc5c4c3)c3cc4c(oc5ccccc54)c-2c31 ; c1ccc2cc3c(cc2c1)c1cccc2c1n3B1c3cc4oc5ccccc5c4cc3N(c3ccc4oc5ccccc5c4c3)c3cc4c(oc5ccccc54)c-2c31 ; CC1(C)c2ccccc2-c2cc(N3c4cc5c(cc4B4c6c3cc3c(oc7ccccc73)c6-c3cccc6c7cc8ccccc8cc7n4c36)C(C)(C)c3ccccc3-5)ccc21] 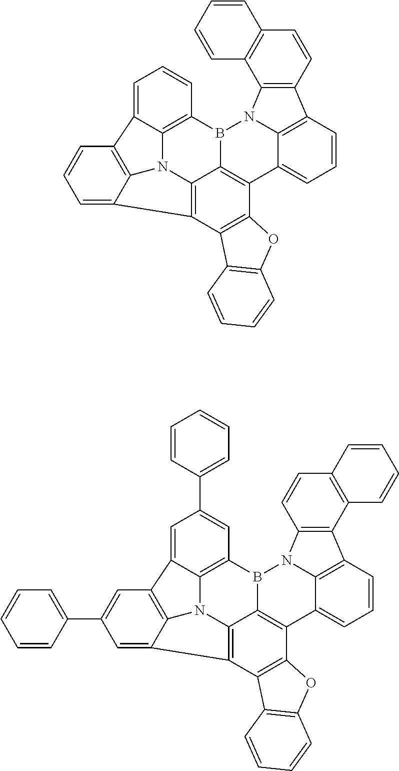 [SMILES: c1ccc2c(c1)ccc1c3cccc4c3n(c21)B1c2cccc3c5cccc6c7c8c(oc9ccccc98)c-4c1c7n(c23)c56 ; c1ccc(-c2cc3c4c(c2)c2cc(-c5ccccc5)cc5c6c7c(oc8ccccc87)c7c(c6n4c25)B3n2c3ccc4ccccc4c3c3cccc-7c32)cc1] 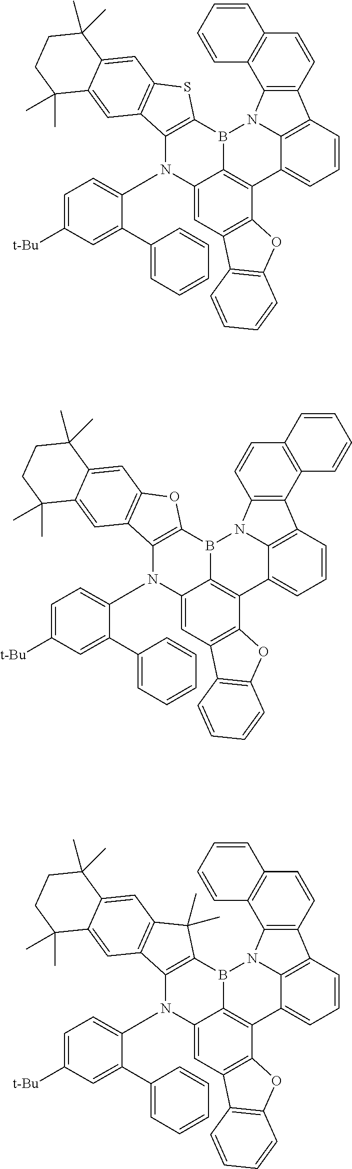 [SMILES: CC(C)(C)c1ccc(N2c3cc4c(oc5ccccc54)c4c3B(c3sc5cc6c(cc5c32)C(C)(C)CCC6(C)C)n2c3c-4cccc3c3ccc4ccccc4c32)c(-c2ccccc2)c1 ; CC(C)(C)c1ccc(N2c3cc4c(oc5ccccc54)c4c3B(c3oc5cc6c(cc5c32)C(C)(C)CCC6(C)C)n2c3ccc5ccccc5c3c3cccc-4c32)c(-c2ccccc2)c1 ; CC(C)(C)c1ccc(N2C3=C(B4c5c2cc2c(oc6ccccc62)c5-c2cccc5c6ccc7ccccc7c6n4c25)C(C)(C)c2cc4c(cc23)C(C)(C)CCC4(C)C)c(-c2ccccc2)c1] 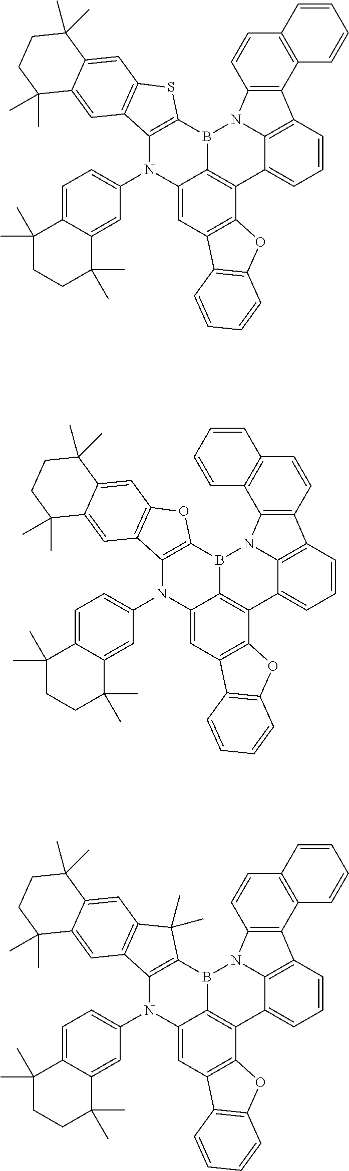 [SMILES: CC1(C)CCC(C)(C)c2cc(N3c4cc5c(oc6ccccc65)c5c4B(c4sc6cc7c(cc6c43)C(C)(C)CCC7(C)C)n3c4ccc6ccccc6c4c4cccc-5c43)ccc21 ; CC1(C)CCC(C)(C)c2cc(N3c4cc5c(oc6ccccc65)c5c4B(c4oc6cc7c(cc6c43)C(C)(C)CCC7(C)C)n3c4c-5cccc4c4ccc5ccccc5c43)ccc21 ; CC1(C)CCC(C)(C)c2cc(N3C4=C(B5c6c3cc3c(oc7ccccc73)c6-c3cccc6c7c8ccccc8ccc7n5c36)C(C)(C)c3cc5c(cc34)C(C)(C)CCC5(C)C)ccc21] 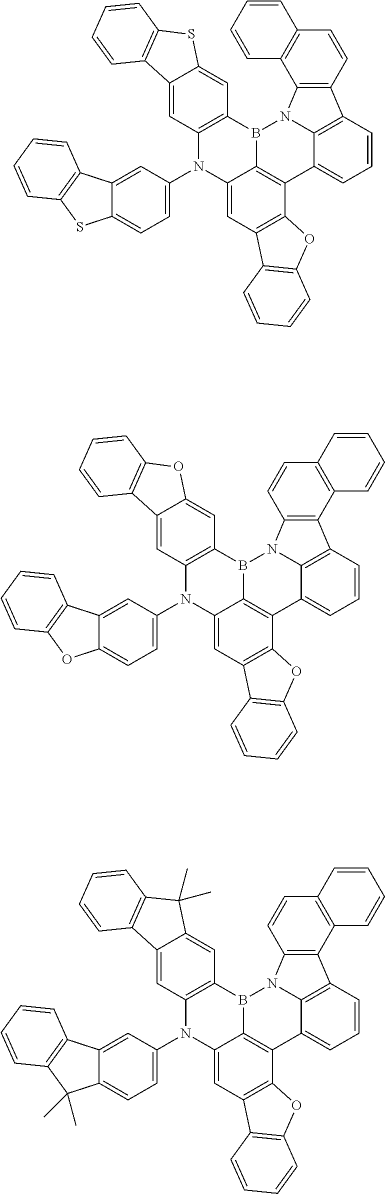 [SMILES: c1ccc2c(c1)ccc1c3cccc4c3n(c21)B1c2cc3sc5ccccc5c3cc2N(c2ccc3sc5ccccc5c3c2)c2cc3c(oc5ccccc53)c-4c21 ; c1ccc2c(c1)ccc1c2c2cccc3c2n1B1c2cc4oc5ccccc5c4cc2N(c2ccc4oc5ccccc5c4c2)c2cc4c(oc5ccccc54)c-3c21 ; CC1(C)c2ccccc2-c2cc(N3c4cc5c(cc4B4c6c3cc3c(oc7ccccc73)c6-c3cccc6c7c8ccccc8ccc7n4c36)C(C)(C)c3ccccc3-5)ccc21] 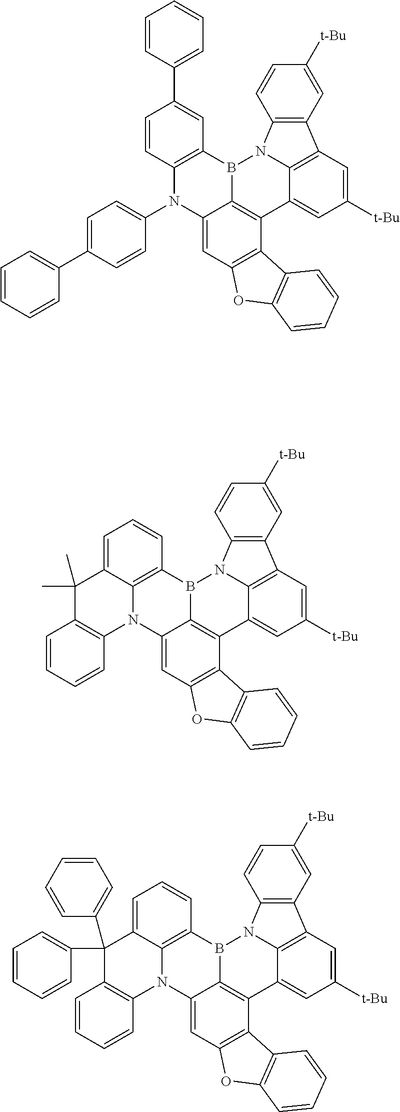 [SMILES: CC(C)(C)c1ccc2c(c1)c1cc(C(C)(C)C)cc3c1n2B1c2cc(-c4ccccc4)ccc2N(c2ccc(-c4ccccc4)cc2)c2cc4oc5ccccc5c4c-3c21 ; CC(C)(C)c1ccc2c(c1)c1cc(C(C)(C)C)cc3c1n2B1c2cccc4c2N(c2ccccc2C4(C)C)c2cc4oc5ccccc5c4c-3c21 ; CC(C)(C)c1ccc2c(c1)c1cc(C(C)(C)C)cc3c1n2B1c2cccc4c2N(c2ccccc2C4(c2ccccc2)c2ccccc2)c2cc4oc5ccccc5c4c-3c21] 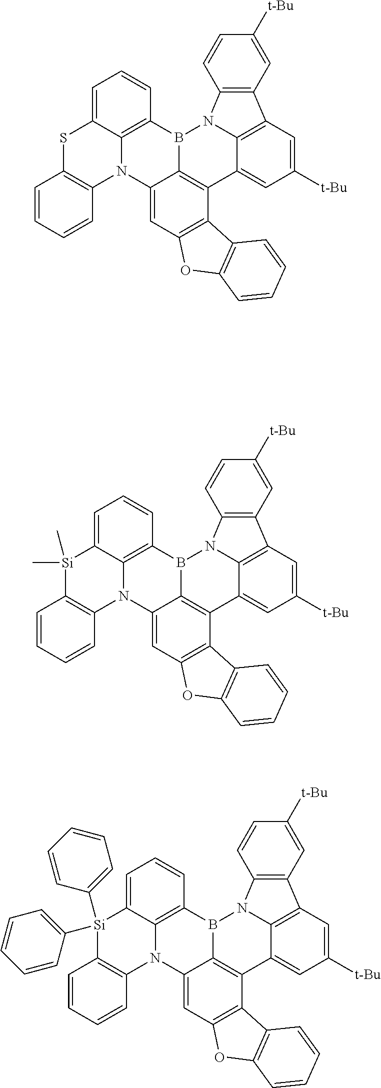 [SMILES: CC(C)(C)c1ccc2c(c1)c1cc(C(C)(C)C)cc3c1n2B1c2cccc4c2N(c2ccccc2S4)c2cc4oc5ccccc5c4c-3c21 ; CC(C)(C)c1ccc2c(c1)c1cc(C(C)(C)C)cc3c1n2B1c2cccc4c2N(c2ccccc2[Si]4(C)C)c2cc4oc5ccccc5c4c-3c21 ; CC(C)(C)c1ccc2c(c1)c1cc(C(C)(C)C)cc3c1n2B1c2cccc4c2N(c2ccccc2[Si]4(c2ccccc2)c2ccccc2)c2cc4oc5ccccc5c4c-3c21] 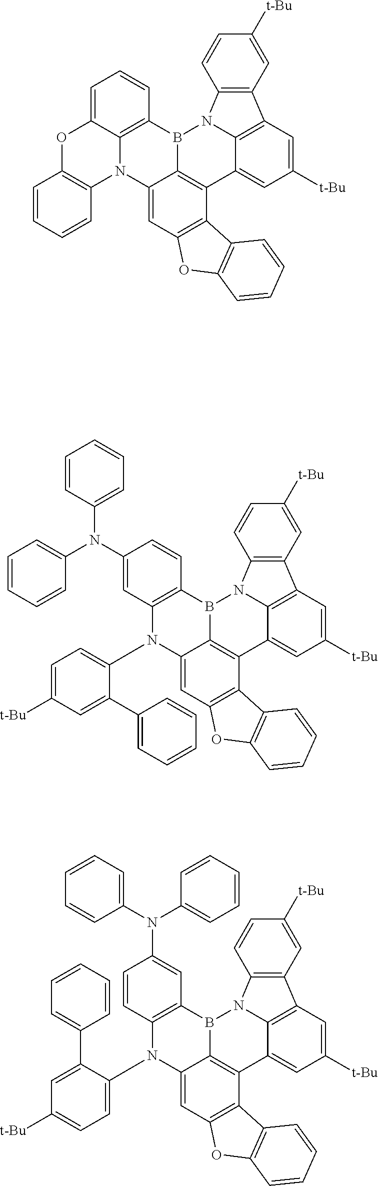 [SMILES: CC(C)(C)c1ccc2c(c1)c1cc(C(C)(C)C)cc3c1n2B1c2cccc4c2N(c2ccccc2O4)c2cc4oc5ccccc5c4c-3c21 ; CC(C)(C)c1ccc(N2c3cc(N(c4ccccc4)c4ccccc4)ccc3B3c4c2cc2oc5ccccc5c2c4-c2cc(C(C)(C)C)cc4c5cc(C(C)(C)C)ccc5n3c24)c(-c2ccccc2)c1 ; CC(C)(C)c1ccc(N2c3ccc(N(c4ccccc4)c4ccccc4)cc3B3c4c2cc2oc5ccccc5c2c4-c2cc(C(C)(C)C)cc4c5cc(C(C)(C)C)ccc5n3c24)c(-c2ccccc2)c1] 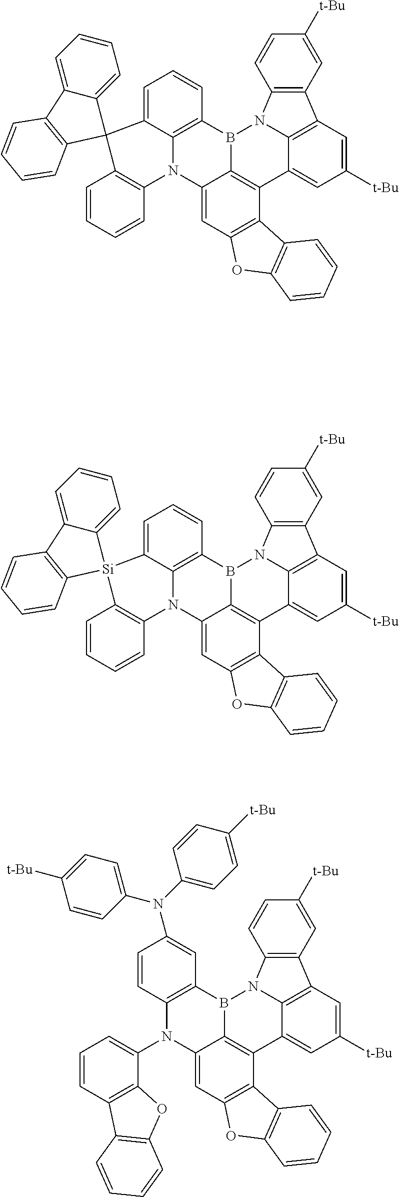 [SMILES: CC(C)(C)c1ccc2c(c1)c1cc(C(C)(C)C)cc3c1n2B1c2cccc4c2N(c2ccccc2C42c4ccccc4-c4ccccc42)c2cc4oc5ccccc5c4c-3c21 ; CC(C)(C)c1ccc2c(c1)c1cc(C(C)(C)C)cc3c1n2B1c2cccc4c2N(c2ccccc2[Si]42c4ccccc4-c4ccccc42)c2cc4oc5ccccc5c4c-3c21 ; CC(C)(C)c1ccc(N(c2ccc(C(C)(C)C)cc2)c2ccc3c(c2)B2c4c(cc5oc6ccccc6c5c4-c4cc(C(C)(C)C)cc5c6cc(C(C)(C)C)ccc6n2c45)N3c2cccc3c2oc2ccccc23)cc1] 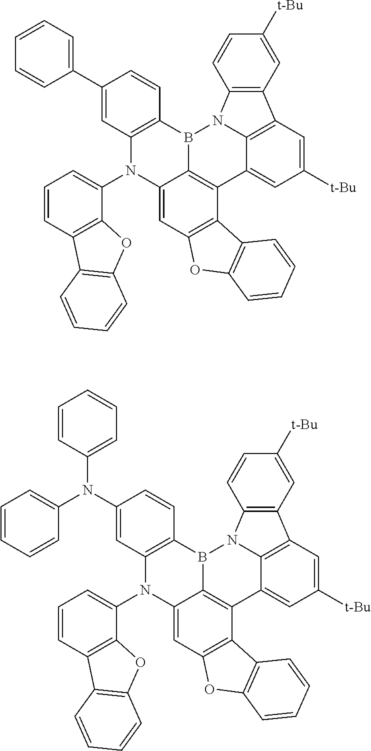 [SMILES: CC(C)(C)c1ccc2c(c1)c1cc(C(C)(C)C)cc3c1n2B1c2ccc(-c4ccccc4)cc2N(c2cccc4c2oc2ccccc24)c2cc4oc5ccccc5c4c-3c21 ; CC(C)(C)c1ccc2c(c1)c1cc(C(C)(C)C)cc3c1n2B1c2ccc(N(c4ccccc4)c4ccccc4)cc2N(c2cccc4c2oc2ccccc24)c2cc4oc5ccccc5c4c-3c21] 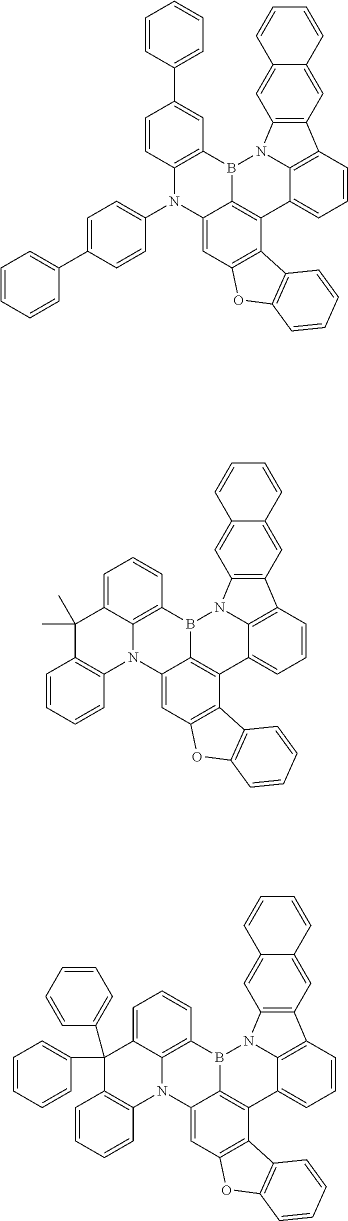 [SMILES: c1ccc(-c2ccc(N3c4ccc(-c5ccccc5)cc4B4c5c3cc3oc6ccccc6c3c5-c3cccc5c6cc7ccccc7cc6n4c35)cc2)cc1 ; CC1(C)c2ccccc2N2c3cc4oc5ccccc5c4c4c3B(c3cccc1c32)n1c2cc3ccccc3cc2c2cccc-4c21 ; c1ccc(C2(c3ccccc3)c3ccccc3N3c4cc5oc6ccccc6c5c5c4B(c4cccc2c43)n2c3cc4ccccc4cc3c3cccc-5c32)cc1] 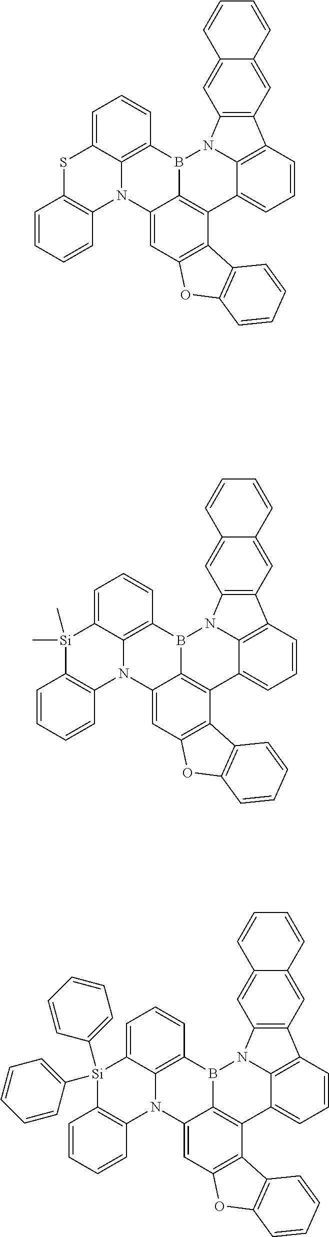 [SMILES: c1ccc2c(c1)Sc1cccc3c1N2c1cc2oc4ccccc4c2c2c1B3n1c3cc4ccccc4cc3c3cccc-2c31 ; C[Si]1(C)c2ccccc2N2c3cc4oc5ccccc5c4c4c3B(c3cccc1c32)n1c2cc3ccccc3cc2c2cccc-4c21 ; c1ccc([Si]2(c3ccccc3)c3ccccc3N3c4cc5oc6ccccc6c5c5c4B(c4cccc2c43)n2c3cc4ccccc4cc3c3cccc-5c32)cc1] 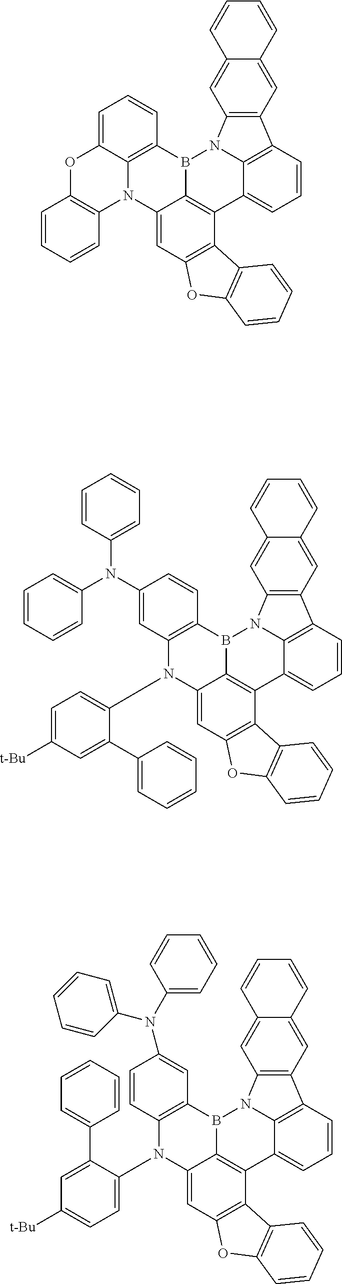 [SMILES: c1ccc2c(c1)Oc1cccc3c1N2c1cc2oc4ccccc4c2c2c1B3n1c3cc4ccccc4cc3c3cccc-2c31 ; CC(C)(C)c1ccc(N2c3cc(N(c4ccccc4)c4ccccc4)ccc3B3c4c2cc2oc5ccccc5c2c4-c2cccc4c5cc6ccccc6cc5n3c24)c(-c2ccccc2)c1 ; CC(C)(C)c1ccc(N2c3ccc(N(c4ccccc4)c4ccccc4)cc3B3c4c2cc2oc5ccccc5c2c4-c2cccc4c5cc6ccccc6cc5n3c24)c(-c2ccccc2)c1] 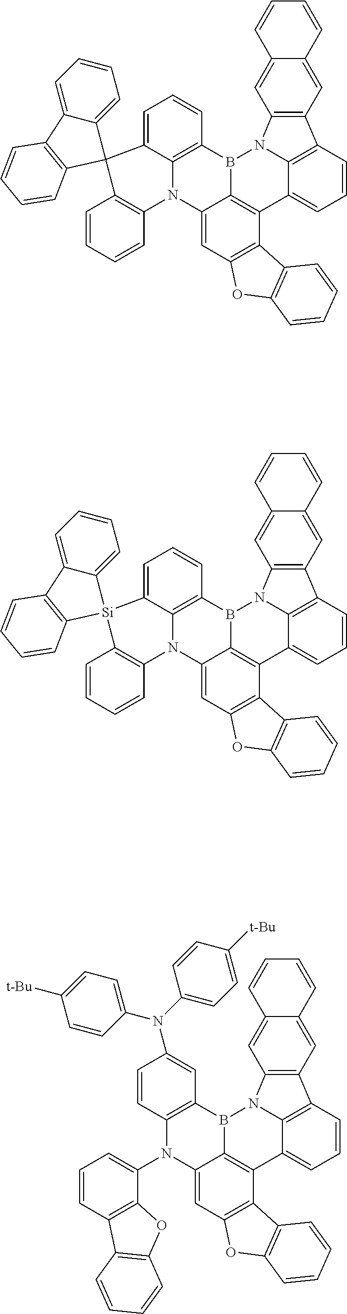 [SMILES: c1ccc2c(c1)-c1ccccc1C21c2ccccc2N2c3cc4oc5ccccc5c4c4c3B(c3cccc1c32)n1c2cc3ccccc3cc2c2cccc-4c21 ; c1ccc2c(c1)-c1ccccc1[Si]21c2ccccc2N2c3cc4oc5ccccc5c4c4c3B(c3cccc1c32)n1c2cc3ccccc3cc2c2cccc-4c21 ; CC(C)(C)c1ccc(N(c2ccc(C(C)(C)C)cc2)c2ccc3c(c2)B2c4c(cc5oc6ccccc6c5c4-c4cccc5c6cc7ccccc7cc6n2c45)N3c2cccc3c2oc2ccccc23)cc1] 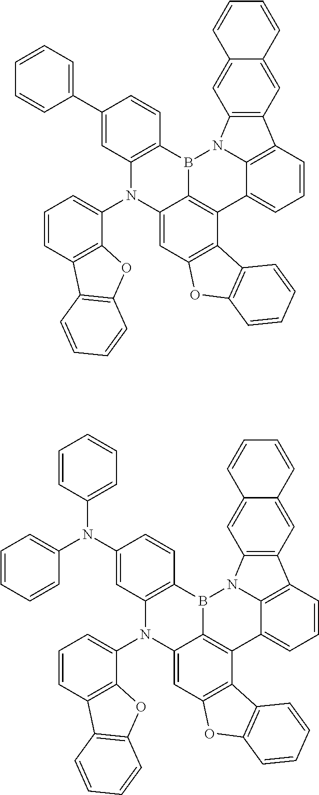 [SMILES: c1ccc(-c2ccc3c(c2)N(c2cccc4c2oc2ccccc24)c2cc4oc5ccccc5c4c4c2B3n2c3cc5ccccc5cc3c3cccc-4c32)cc1 ; c1ccc(N(c2ccccc2)c2ccc3c(c2)N(c2cccc4c2oc2ccccc24)c2cc4oc5ccccc5c4c4c2B3n2c3cc5ccccc5cc3c3cccc-4c32)cc1] 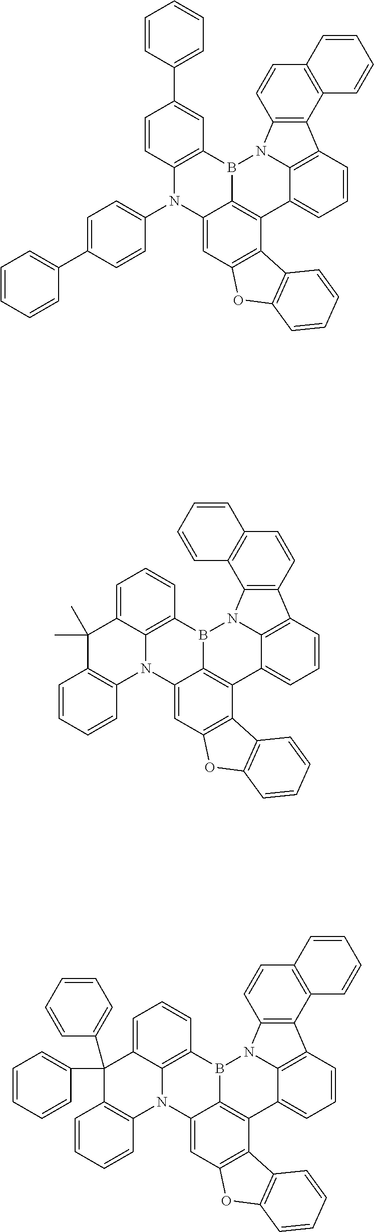 [SMILES: c1ccc(-c2ccc(N3c4ccc(-c5ccccc5)cc4B4c5c3cc3oc6ccccc6c3c5-c3cccc5c6c7ccccc7ccc6n4c35)cc2)cc1 ; CC1(C)c2ccccc2N2c3cc4oc5ccccc5c4c4c3B(c3cccc1c32)n1c2c-4cccc2c2ccc3ccccc3c21 ; c1ccc(C2(c3ccccc3)c3ccccc3N3c4cc5oc6ccccc6c5c5c4B(c4cccc2c43)n2c3ccc4ccccc4c3c3cccc-5c32)cc1] 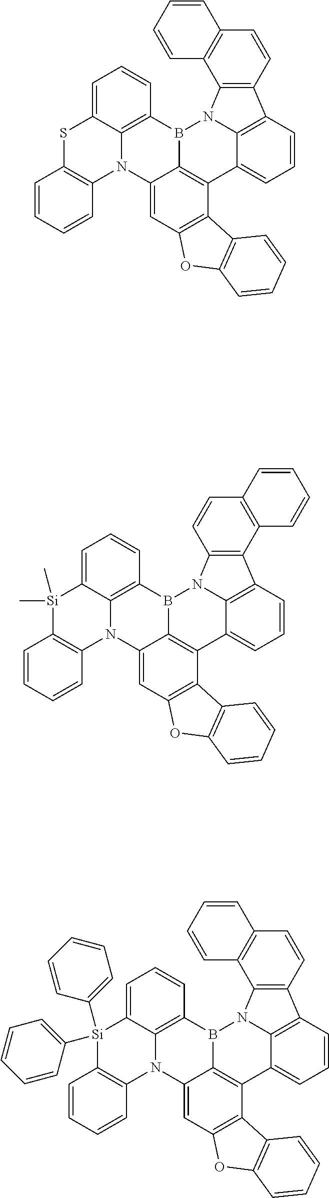 [SMILES: c1ccc2c(c1)Sc1cccc3c1N2c1cc2oc4ccccc4c2c2c1B3n1c3c-2cccc3c2ccc3ccccc3c21 ; C[Si]1(C)c2ccccc2N2c3cc4oc5ccccc5c4c4c3B(c3cccc1c32)n1c2ccc3ccccc3c2c2cccc-4c21 ; c1ccc([Si]2(c3ccccc3)c3ccccc3N3c4cc5oc6ccccc6c5c5c4B(c4cccc2c43)n2c3c-5cccc3c3ccc4ccccc4c32)cc1] 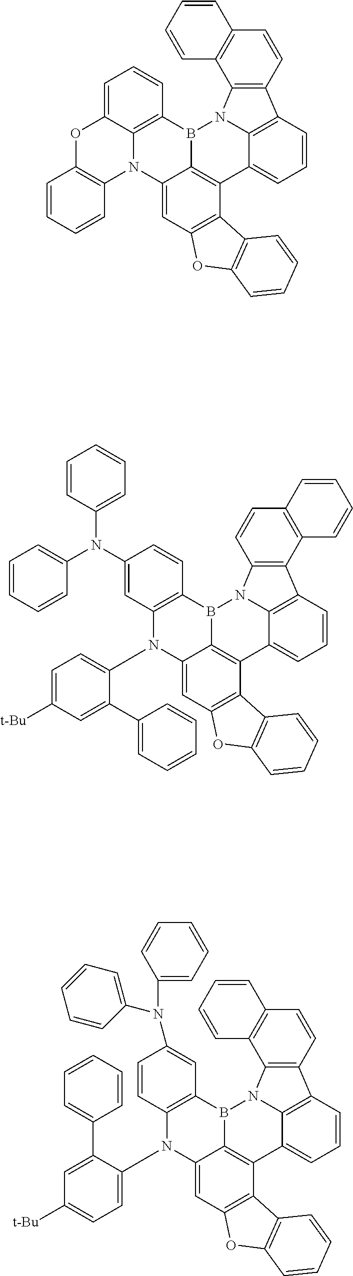 [SMILES: c1ccc2c(c1)Oc1cccc3c1N2c1cc2oc4ccccc4c2c2c1B3n1c3c-2cccc3c2ccc3ccccc3c21 ; CC(C)(C)c1ccc(N2c3cc(N(c4ccccc4)c4ccccc4)ccc3B3c4c2cc2oc5ccccc5c2c4-c2cccc4c5c6ccccc6ccc5n3c24)c(-c2ccccc2)c1 ; CC(C)(C)c1ccc(N2c3ccc(N(c4ccccc4)c4ccccc4)cc3B3c4c2cc2oc5ccccc5c2c4-c2cccc4c5ccc6ccccc6c5n3c24)c(-c2ccccc2)c1] 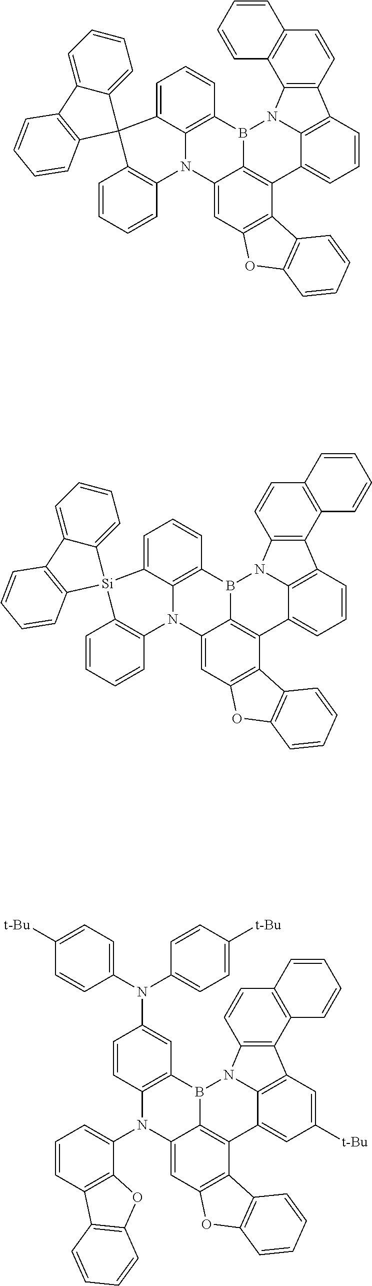 [SMILES: c1ccc2c(c1)-c1ccccc1C21c2ccccc2N2c3cc4oc5ccccc5c4c4c3B(c3cccc1c32)n1c2c-4cccc2c2ccc3ccccc3c21 ; c1ccc2c(c1)-c1ccccc1[Si]21c2ccccc2N2c3cc4oc5ccccc5c4c4c3B(c3cccc1c32)n1c2ccc3ccccc3c2c2cccc-4c21 ; CC(C)(C)c1ccc(N(c2ccc(C(C)(C)C)cc2)c2ccc3c(c2)B2c4c(cc5oc6ccccc6c5c4-c4cc(C(C)(C)C)cc5c6c7ccccc7ccc6n2c45)N3c2cccc3c2oc2ccccc23)cc1] 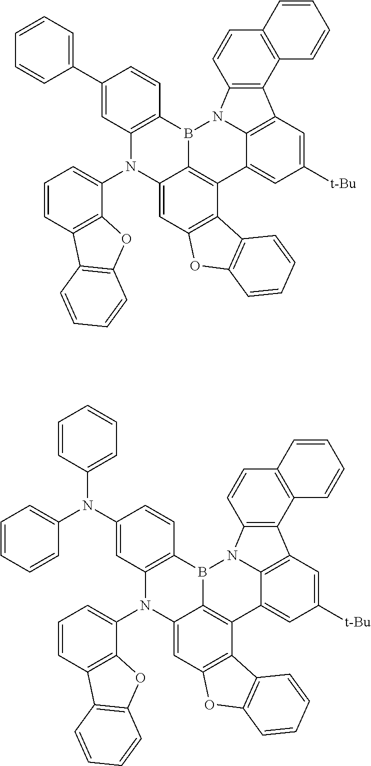 [SMILES: CC(C)(C)c1cc2c3c(c1)c1c4ccccc4ccc1n3B1c3ccc(-c4ccccc4)cc3N(c3cccc4c3oc3ccccc34)c3cc4oc5ccccc5c4c-2c31 ; CC(C)(C)c1cc2c3c(c1)c1c4ccccc4ccc1n3B1c3ccc(N(c4ccccc4)c4ccccc4)cc3N(c3cccc4c3oc3ccccc34)c3cc4oc5ccccc5c4c-2c31] 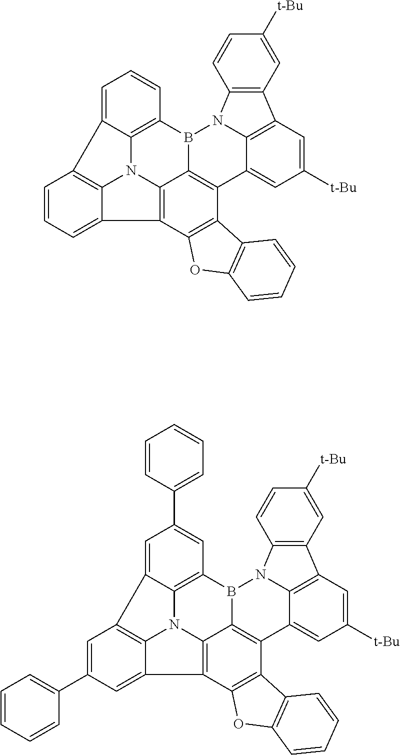 [SMILES: CC(C)(C)c1ccc2c(c1)c1cc(C(C)(C)C)cc3c1n2B1c2cccc4c5cccc6c7c8oc9ccccc9c8c-3c1c7n(c24)c56 ; CC(C)(C)c1ccc2c(c1)c1cc(C(C)(C)C)cc3c1n2B1c2cc(-c4ccccc4)cc4c5cc(-c6ccccc6)cc6c7c8oc9ccccc9c8c-3c1c7n(c24)c56] 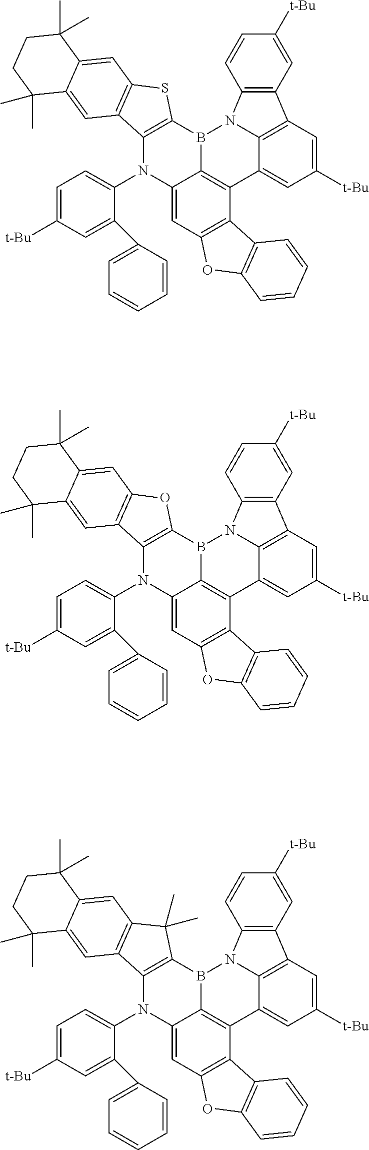 [SMILES: CC(C)(C)c1ccc(N2c3cc4oc5ccccc5c4c4c3B(c3sc5cc6c(cc5c32)C(C)(C)CCC6(C)C)n2c3ccc(C(C)(C)C)cc3c3cc(C(C)(C)C)cc-4c32)c(-c2ccccc2)c1 ; CC(C)(C)c1ccc(N2c3cc4oc5ccccc5c4c4c3B(c3oc5cc6c(cc5c32)C(C)(C)CCC6(C)C)n2c3ccc(C(C)(C)C)cc3c3cc(C(C)(C)C)cc-4c32)c(-c2ccccc2)c1 ; CC(C)(C)c1ccc(N2C3=C(B4c5c2cc2oc6ccccc6c2c5-c2cc(C(C)(C)C)cc5c6cc(C(C)(C)C)ccc6n4c25)C(C)(C)c2cc4c(cc23)C(C)(C)CCC4(C)C)c(-c2ccccc2)c1] 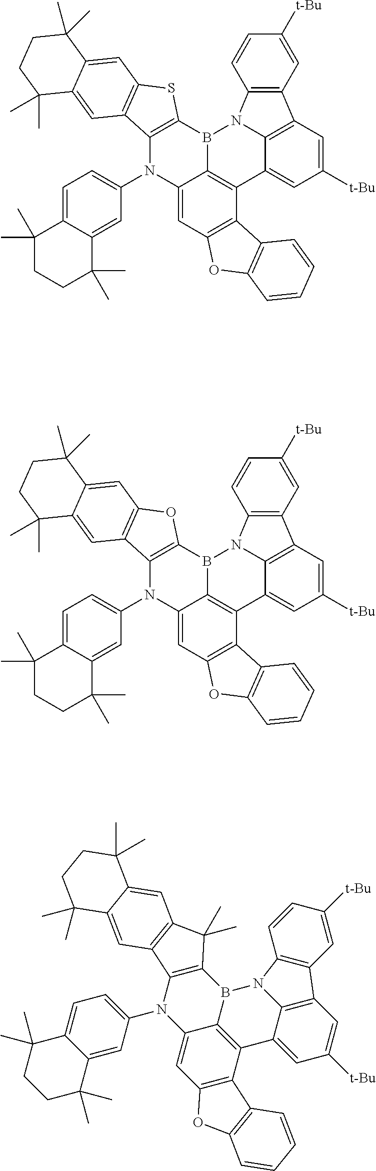 [SMILES: CC(C)(C)c1ccc2c(c1)c1cc(C(C)(C)C)cc3c1n2B1c2sc4cc5c(cc4c2N(c2ccc4c(c2)C(C)(C)CCC4(C)C)c2cc4oc6ccccc6c4c-3c21)C(C)(C)CCC5(C)C ; CC(C)(C)c1ccc2c(c1)c1cc(C(C)(C)C)cc3c1n2B1c2oc4cc5c(cc4c2N(c2ccc4c(c2)C(C)(C)CCC4(C)C)c2cc4oc6ccccc6c4c-3c21)C(C)(C)CCC5(C)C ; CC(C)(C)c1ccc2c(c1)c1cc(C(C)(C)C)cc3c1n2B1C2=C(c4cc5c(cc4C2(C)C)C(C)(C)CCC5(C)C)N(c2ccc4c(c2)C(C)(C)CCC4(C)C)c2cc4oc5ccccc5c4c-3c21] 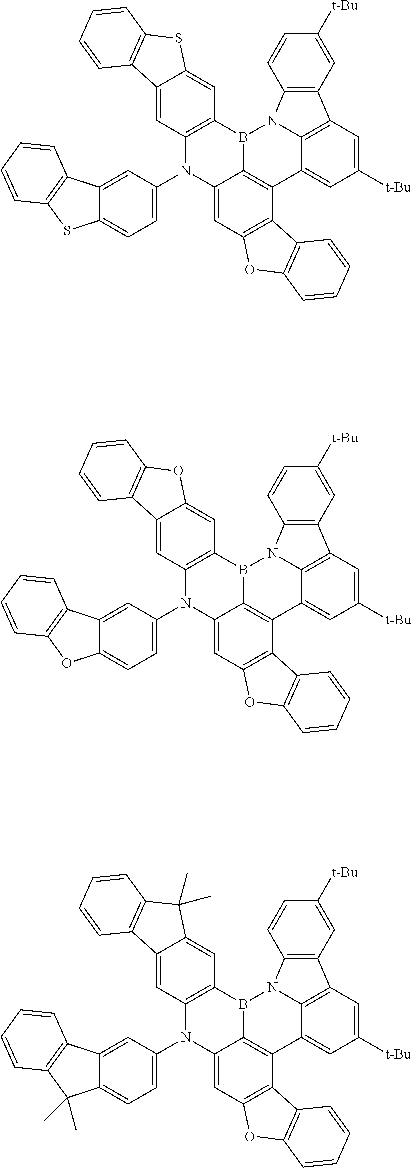 [SMILES: CC(C)(C)c1ccc2c(c1)c1cc(C(C)(C)C)cc3c1n2B1c2cc4sc5ccccc5c4cc2N(c2ccc4sc5ccccc5c4c2)c2cc4oc5ccccc5c4c-3c21 ; CC(C)(C)c1ccc2c(c1)c1cc(C(C)(C)C)cc3c1n2B1c2cc4oc5ccccc5c4cc2N(c2ccc4oc5ccccc5c4c2)c2cc4oc5ccccc5c4c-3c21 ; CC(C)(C)c1ccc2c(c1)c1cc(C(C)(C)C)cc3c1n2B1c2cc4c(cc2N(c2ccc5c(c2)-c2ccccc2C5(C)C)c2cc5oc6ccccc6c5c-3c21)-c1ccccc1C4(C)C] 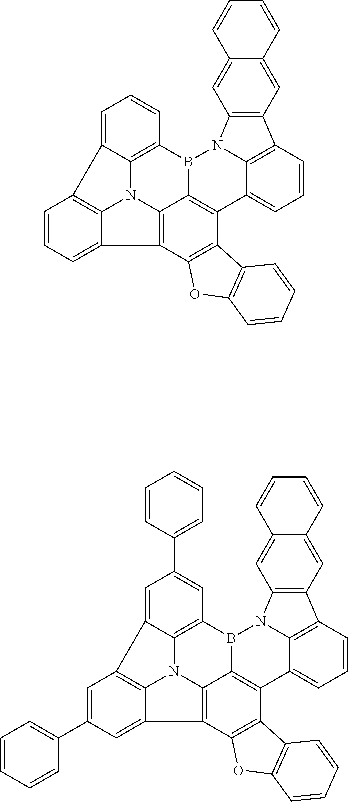 [SMILES: c1ccc2cc3c(cc2c1)c1cccc2c1n3B1c3cccc4c5cccc6c7c8oc9ccccc9c8c-2c1c7n(c34)c56 ; c1ccc(-c2cc3c4c(c2)c2cc(-c5ccccc5)cc5c6c7oc8ccccc8c7c7c(c6n4c25)B3n2c3cc4ccccc4cc3c3cccc-7c32)cc1] 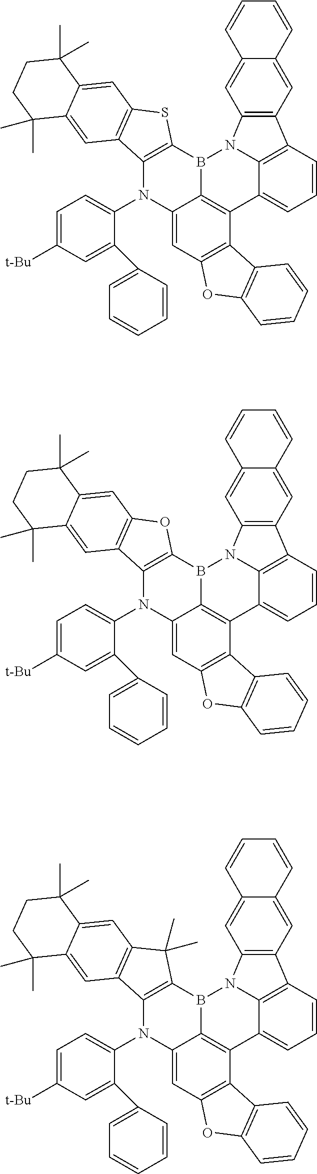 [SMILES: CC(C)(C)c1ccc(N2c3cc4oc5ccccc5c4c4c3B(c3sc5cc6c(cc5c32)C(C)(C)CCC6(C)C)n2c3cc5ccccc5cc3c3cccc-4c32)c(-c2ccccc2)c1 ; CC(C)(C)c1ccc(N2c3cc4oc5ccccc5c4c4c3B(c3oc5cc6c(cc5c32)C(C)(C)CCC6(C)C)n2c3cc5ccccc5cc3c3cccc-4c32)c(-c2ccccc2)c1 ; CC(C)(C)c1ccc(N2C3=C(B4c5c2cc2oc6ccccc6c2c5-c2cccc5c6cc7ccccc7cc6n4c25)C(C)(C)c2cc4c(cc23)C(C)(C)CCC4(C)C)c(-c2ccccc2)c1] 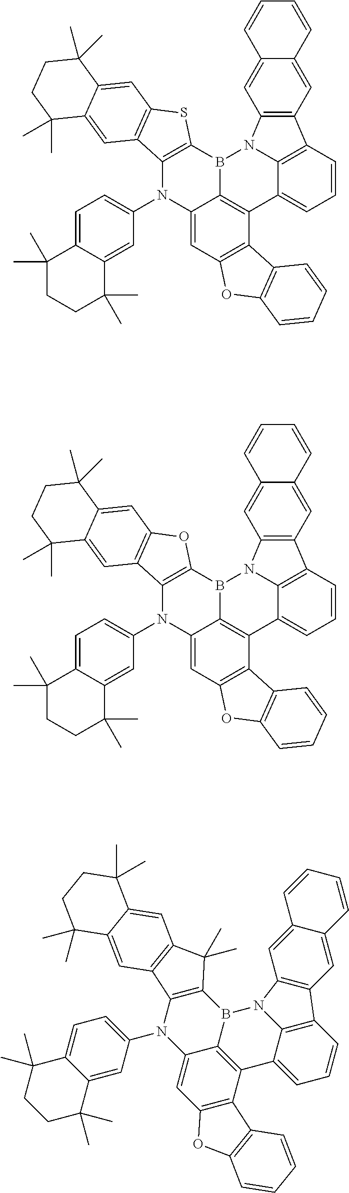 [SMILES: CC1(C)CCC(C)(C)c2cc(N3c4cc5oc6ccccc6c5c5c4B(c4sc6cc7c(cc6c43)C(C)(C)CCC7(C)C)n3c4cc6ccccc6cc4c4cccc-5c43)ccc21 ; CC1(C)CCC(C)(C)c2cc(N3c4cc5oc6ccccc6c5c5c4B(c4oc6cc7c(cc6c43)C(C)(C)CCC7(C)C)n3c4cc6ccccc6cc4c4cccc-5c43)ccc21 ; CC1(C)CCC(C)(C)c2cc(N3C4=C(B5c6c3cc3oc7ccccc7c3c6-c3cccc6c7cc8ccccc8cc7n5c36)C(C)(C)c3cc5c(cc34)C(C)(C)CCC5(C)C)ccc21] 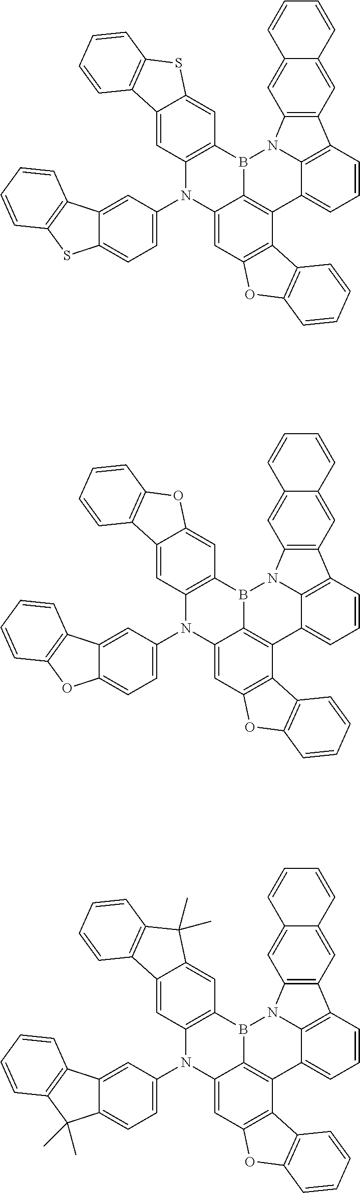 [SMILES: c1ccc2cc3c(cc2c1)c1cccc2c1n3B1c3cc4sc5ccccc5c4cc3N(c3ccc4sc5ccccc5c4c3)c3cc4oc5ccccc5c4c-2c31 ; c1ccc2cc3c(cc2c1)c1cccc2c1n3B1c3cc4oc5ccccc5c4cc3N(c3ccc4oc5ccccc5c4c3)c3cc4oc5ccccc5c4c-2c31 ; CC1(C)c2ccccc2-c2cc(N3c4cc5c(cc4B4c6c3cc3oc7ccccc7c3c6-c3cccc6c7cc8ccccc8cc7n4c36)C(C)(C)c3ccccc3-5)ccc21] 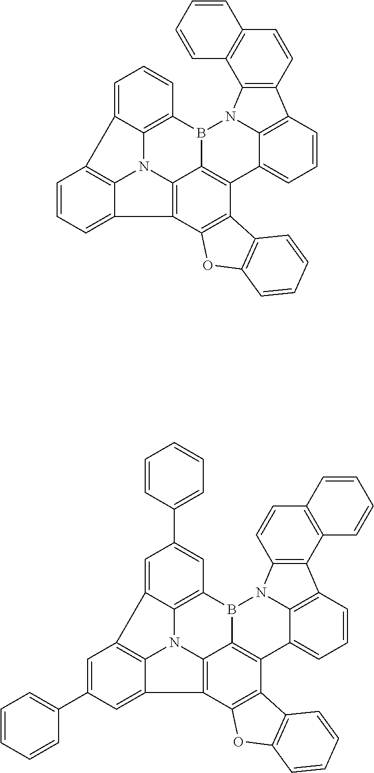 [SMILES: c1ccc2c(c1)ccc1c3cccc4c3n(c21)B1c2cccc3c5cccc6c7c8oc9ccccc9c8c-4c1c7n(c23)c56 ; c1ccc(-c2cc3c4c(c2)c2cc(-c5ccccc5)cc5c6c7oc8ccccc8c7c7c(c6n4c25)B3n2c3ccc4ccccc4c3c3cccc-7c32)cc1] 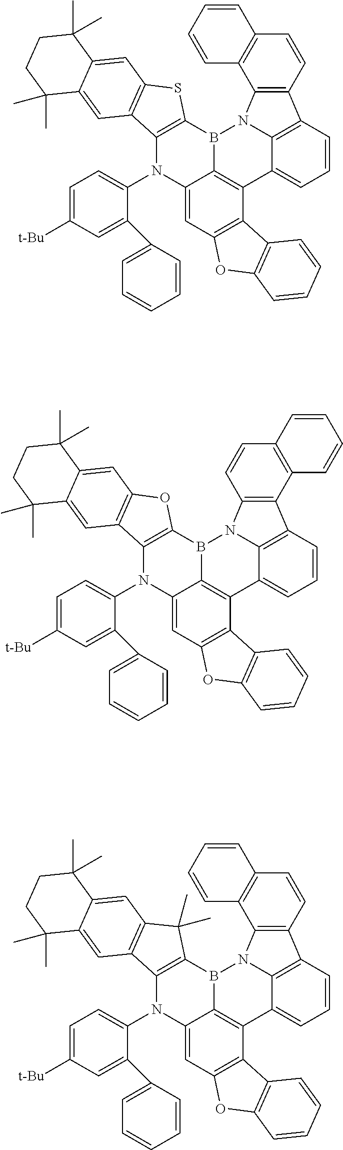 [SMILES: CC(C)(C)c1ccc(N2c3cc4oc5ccccc5c4c4c3B(c3sc5cc6c(cc5c32)C(C)(C)CCC6(C)C)n2c3c-4cccc3c3ccc4ccccc4c32)c(-c2ccccc2)c1 ; CC(C)(C)c1ccc(N2c3cc4oc5ccccc5c4c4c3B(c3oc5cc6c(cc5c32)C(C)(C)CCC6(C)C)n2c3ccc5ccccc5c3c3cccc-4c32)c(-c2ccccc2)c1 ; CC(C)(C)c1ccc(N2C3=C(B4c5c2cc2oc6ccccc6c2c5-c2cccc5c6ccc7ccccc7c6n4c25)C(C)(C)c2cc4c(cc23)C(C)(C)CCC4(C)C)c(-c2ccccc2)c1] 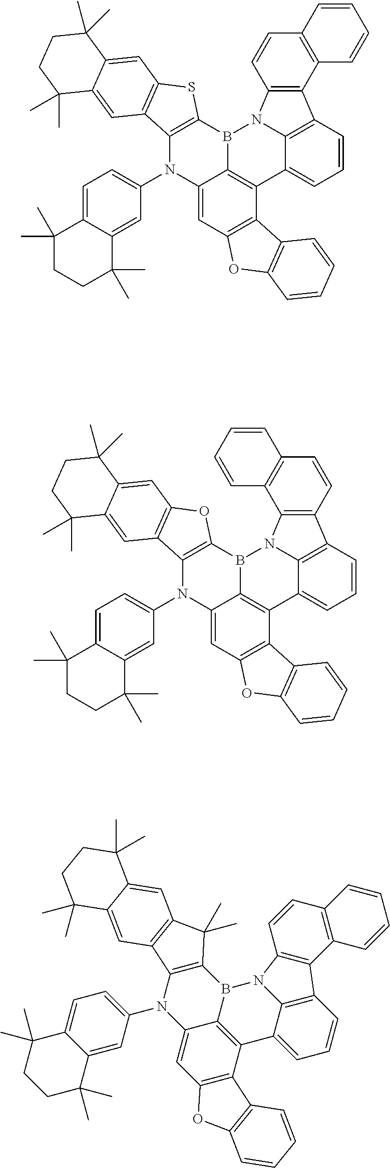 [SMILES: CC1(C)CCC(C)(C)c2cc(N3c4cc5oc6ccccc6c5c5c4B(c4sc6cc7c(cc6c43)C(C)(C)CCC7(C)C)n3c4ccc6ccccc6c4c4cccc-5c43)ccc21 ; CC1(C)CCC(C)(C)c2cc(N3c4cc5oc6ccccc6c5c5c4B(c4oc6cc7c(cc6c43)C(C)(C)CCC7(C)C)n3c4c-5cccc4c4ccc5ccccc5c43)ccc21 ; CC1(C)CCC(C)(C)c2cc(N3C4=C(B5c6c3cc3oc7ccccc7c3c6-c3cccc6c7c8ccccc8ccc7n5c36)C(C)(C)c3cc5c(cc34)C(C)(C)CCC5(C)C)ccc21] 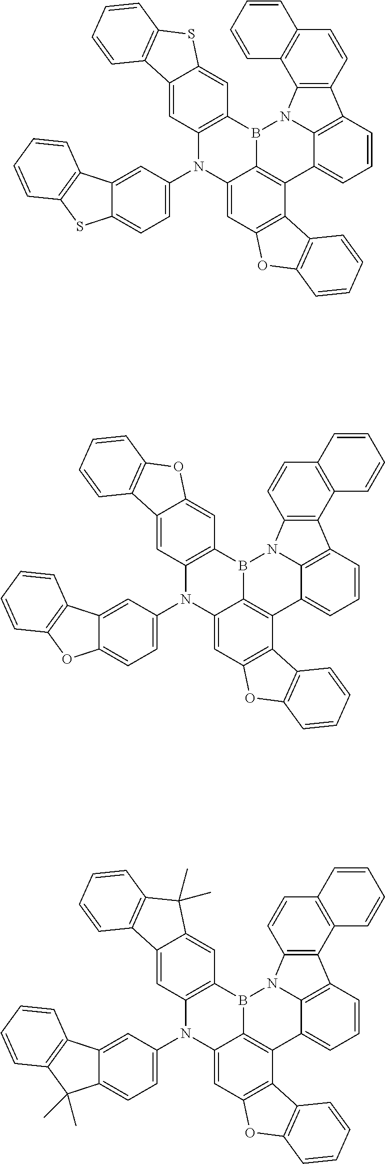 [SMILES: c1ccc2c(c1)ccc1c3cccc4c3n(c21)B1c2cc3sc5ccccc5c3cc2N(c2ccc3sc5ccccc5c3c2)c2cc3oc5ccccc5c3c-4c21 ; c1ccc2c(c1)ccc1c2c2cccc3c2n1B1c2cc4oc5ccccc5c4cc2N(c2ccc4oc5ccccc5c4c2)c2cc4oc5ccccc5c4c-3c21 ; CC1(C)c2ccccc2-c2cc(N3c4cc5c(cc4B4c6c3cc3oc7ccccc7c3c6-c3cccc6c7c8ccccc8ccc7n4c36)C(C)(C)c3ccccc3-5)ccc21] 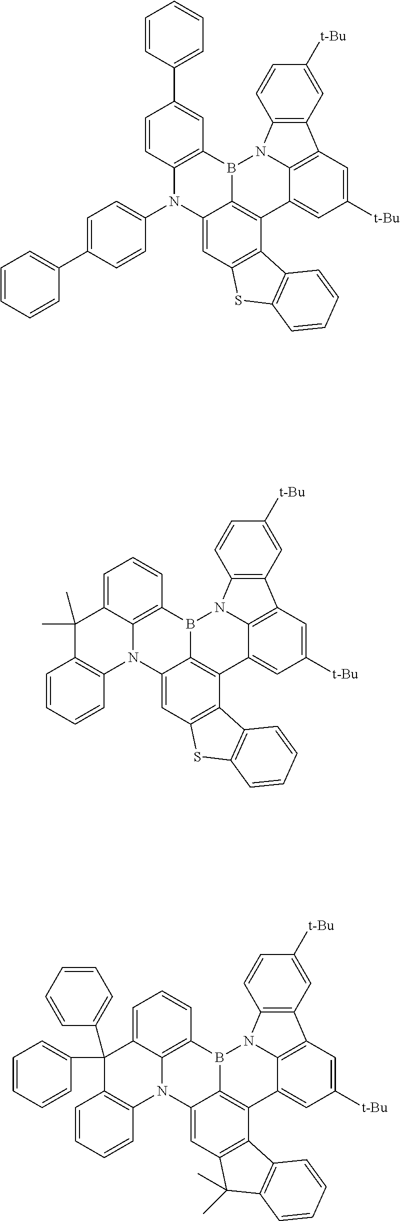 [SMILES: CC(C)(C)c1ccc2c(c1)c1cc(C(C)(C)C)cc3c1n2B1c2cc(-c4ccccc4)ccc2N(c2ccc(-c4ccccc4)cc2)c2cc4sc5ccccc5c4c-3c21 ; CC(C)(C)c1ccc2c(c1)c1cc(C(C)(C)C)cc3c1n2B1c2cccc4c2N(c2ccccc2C4(C)C)c2cc4sc5ccccc5c4c-3c21 ; CC(C)(C)c1ccc2c(c1)c1cc(C(C)(C)C)cc3c1n2B1c2cccc4c2N(c2ccccc2C4(c2ccccc2)c2ccccc2)c2cc4c(c-3c21)-c1ccccc1C4(C)C] 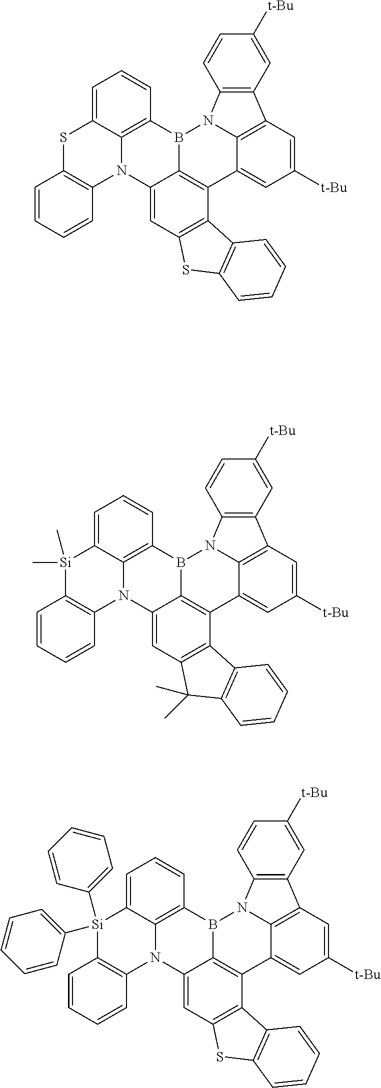 [SMILES: CC(C)(C)c1ccc2c(c1)c1cc(C(C)(C)C)cc3c1n2B1c2cccc4c2N(c2ccccc2S4)c2cc4sc5ccccc5c4c-3c21 ; CC(C)(C)c1ccc2c(c1)c1cc(C(C)(C)C)cc3c1n2B1c2cccc4c2N(c2ccccc2[Si]4(C)C)c2cc4c(c-3c21)-c1ccccc1C4(C)C ; CC(C)(C)c1ccc2c(c1)c1cc(C(C)(C)C)cc3c1n2B1c2cccc4c2N(c2ccccc2[Si]4(c2ccccc2)c2ccccc2)c2cc4sc5ccccc5c4c-3c21] 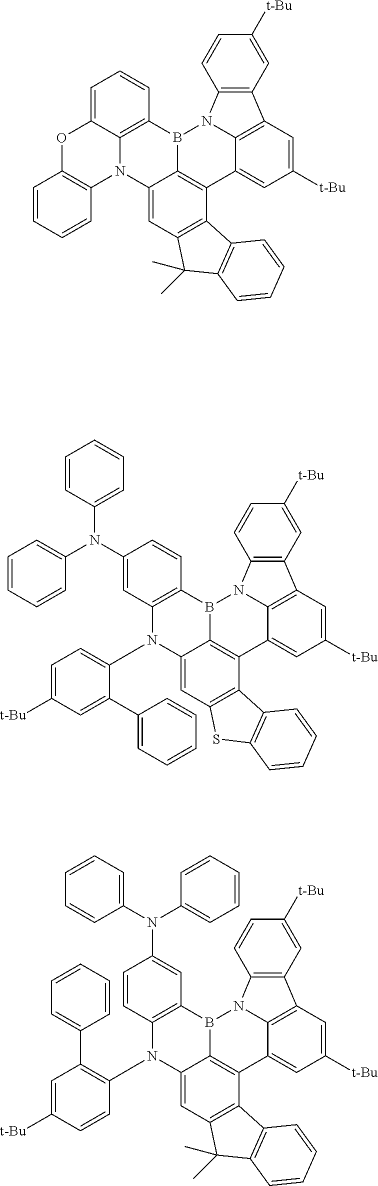 [SMILES: CC(C)(C)c1ccc2c(c1)c1cc(C(C)(C)C)cc3c1n2B1c2cccc4c2N(c2ccccc2O4)c2cc4c(c-3c21)-c1ccccc1C4(C)C ; CC(C)(C)c1ccc(N2c3cc(N(c4ccccc4)c4ccccc4)ccc3B3c4c2cc2sc5ccccc5c2c4-c2cc(C(C)(C)C)cc4c5cc(C(C)(C)C)ccc5n3c24)c(-c2ccccc2)c1 ; CC(C)(C)c1ccc(N2c3ccc(N(c4ccccc4)c4ccccc4)cc3B3c4c2cc2c(c4-c4cc(C(C)(C)C)cc5c6cc(C(C)(C)C)ccc6n3c45)-c3ccccc3C2(C)C)c(-c2ccccc2)c1] 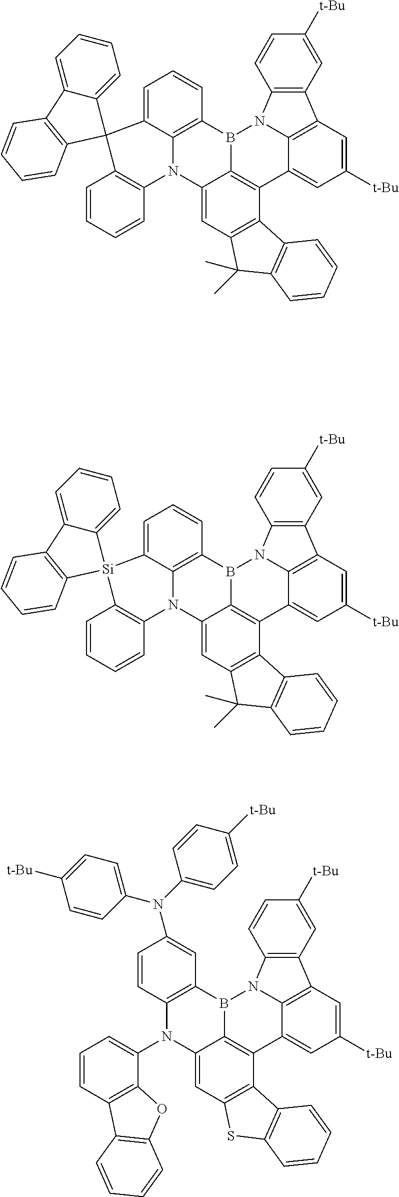 [SMILES: CC(C)(C)c1ccc2c(c1)c1cc(C(C)(C)C)cc3c1n2B1c2cccc4c2N(c2ccccc2C42c4ccccc4-c4ccccc42)c2cc4c(c-3c21)-c1ccccc1C4(C)C ; CC(C)(C)c1ccc2c(c1)c1cc(C(C)(C)C)cc3c1n2B1c2cccc4c2N(c2ccccc2[Si]42c4ccccc4-c4ccccc42)c2cc4c(c-3c21)-c1ccccc1C4(C)C ; CC(C)(C)c1ccc(N(c2ccc(C(C)(C)C)cc2)c2ccc3c(c2)B2c4c(cc5sc6ccccc6c5c4-c4cc(C(C)(C)C)cc5c6cc(C(C)(C)C)ccc6n2c45)N3c2cccc3c2oc2ccccc23)cc1] 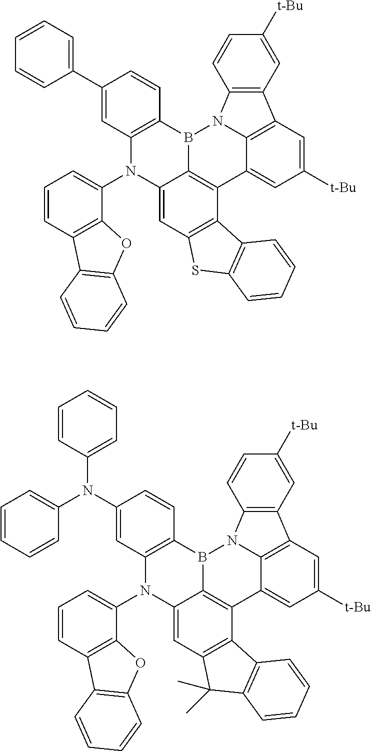 [SMILES: CC(C)(C)c1ccc2c(c1)c1cc(C(C)(C)C)cc3c1n2B1c2ccc(-c4ccccc4)cc2N(c2cccc4c2oc2ccccc24)c2cc4sc5ccccc5c4c-3c21 ; CC(C)(C)c1ccc2c(c1)c1cc(C(C)(C)C)cc3c1n2B1c2ccc(N(c4ccccc4)c4ccccc4)cc2N(c2cccc4c2oc2ccccc24)c2cc4c(c-3c21)-c1ccccc1C4(C)C] 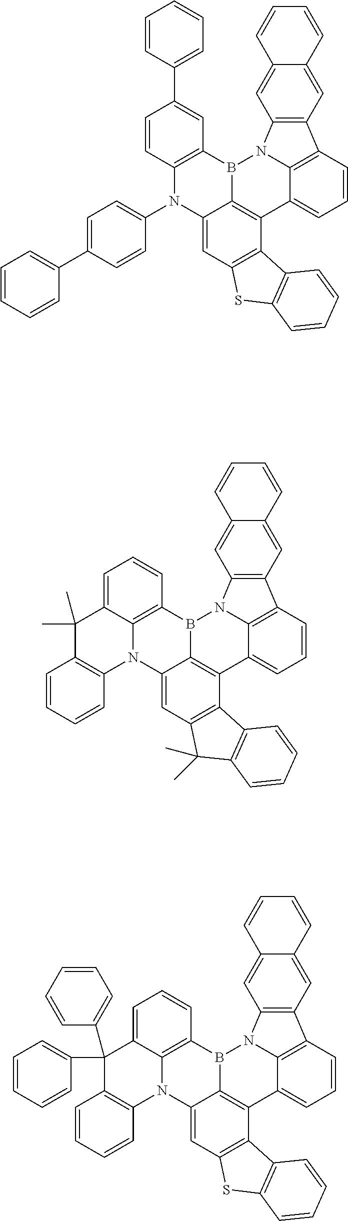 [SMILES: c1ccc(-c2ccc(N3c4ccc(-c5ccccc5)cc4B4c5c3cc3sc6ccccc6c3c5-c3cccc5c6cc7ccccc7cc6n4c35)cc2)cc1 ; CC1(C)c2ccccc2-c2c1cc1c3c2-c2cccc4c5cc6ccccc6cc5n(c24)B3c2cccc3c2N1c1ccccc1C3(C)C ; c1ccc(C2(c3ccccc3)c3ccccc3N3c4cc5sc6ccccc6c5c5c4B(c4cccc2c43)n2c3cc4ccccc4cc3c3cccc-5c32)cc1] 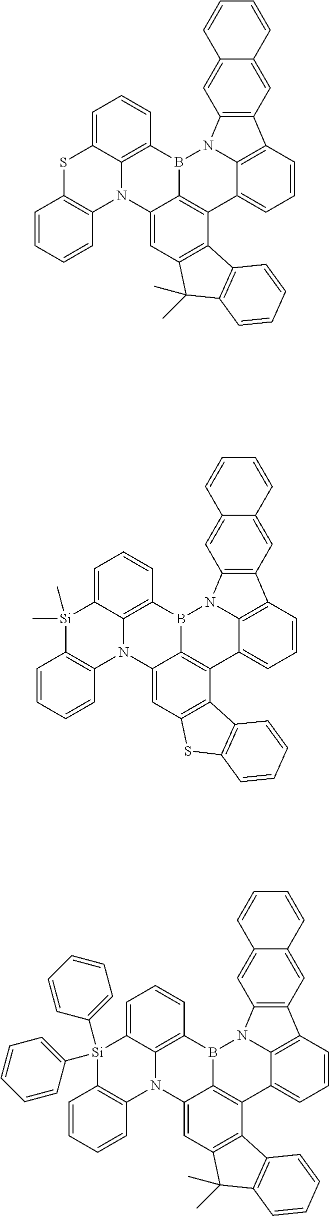 [SMILES: CC1(C)c2ccccc2-c2c1cc1c3c2-c2cccc4c5cc6ccccc6cc5n(c24)B3c2cccc3c2N1c1ccccc1S3 ; C[Si]1(C)c2ccccc2N2c3cc4sc5ccccc5c4c4c3B(c3cccc1c32)n1c2cc3ccccc3cc2c2cccc-4c21 ; CC1(C)c2ccccc2-c2c1cc1c3c2-c2cccc4c5cc6ccccc6cc5n(c24)B3c2cccc3c2N1c1ccccc1[Si]3(c1ccccc1)c1ccccc1] 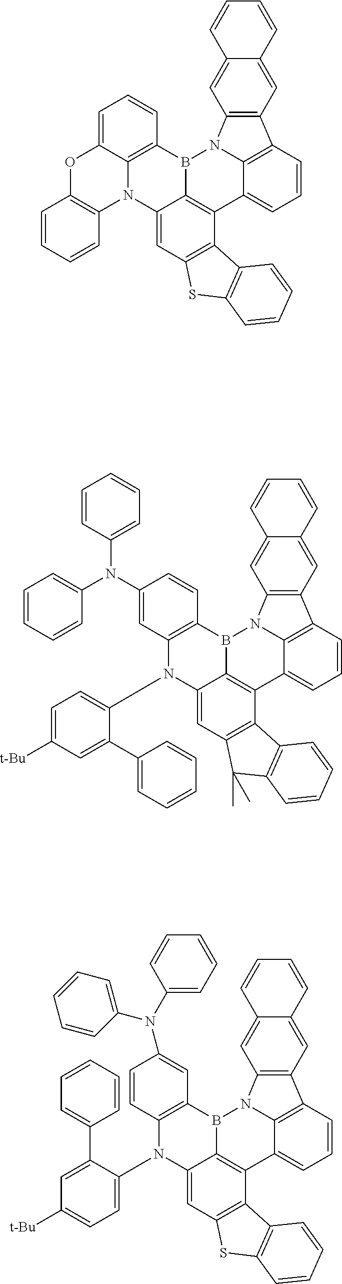 [SMILES: c1ccc2c(c1)Oc1cccc3c1N2c1cc2sc4ccccc4c2c2c1B3n1c3cc4ccccc4cc3c3cccc-2c31 ; CC(C)(C)c1ccc(N2c3cc(N(c4ccccc4)c4ccccc4)ccc3B3c4c2cc2c(c4-c4cccc5c6cc7ccccc7cc6n3c45)-c3ccccc3C2(C)C)c(-c2ccccc2)c1 ; CC(C)(C)c1ccc(N2c3ccc(N(c4ccccc4)c4ccccc4)cc3B3c4c2cc2sc5ccccc5c2c4-c2cccc4c5cc6ccccc6cc5n3c24)c(-c2ccccc2)c1] 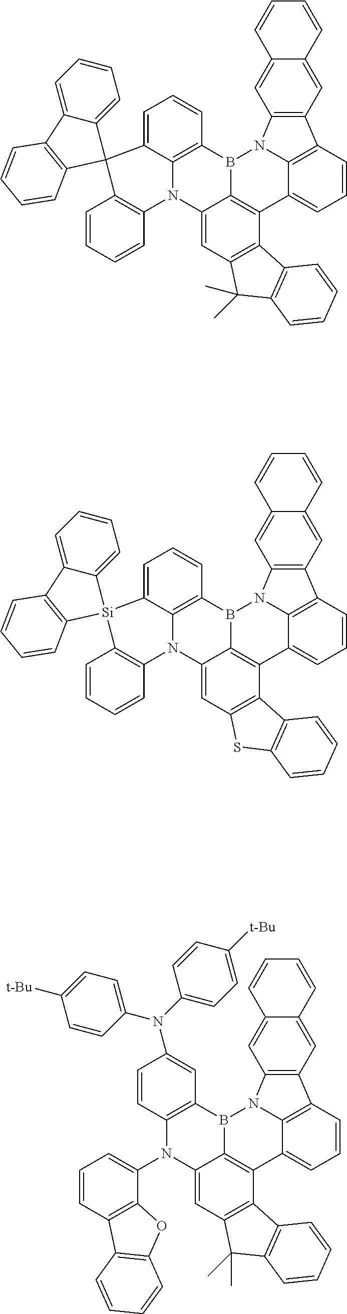 [SMILES: CC1(C)c2ccccc2-c2c1cc1c3c2-c2cccc4c5cc6ccccc6cc5n(c24)B3c2cccc3c2N1c1ccccc1C31c2ccccc2-c2ccccc21 ; c1ccc2c(c1)-c1ccccc1[Si]21c2ccccc2N2c3cc4sc5ccccc5c4c4c3B(c3cccc1c32)n1c2cc3ccccc3cc2c2cccc-4c21 ; CC(C)(C)c1ccc(N(c2ccc(C(C)(C)C)cc2)c2ccc3c(c2)B2c4c(cc5c(c4-c4cccc6c7cc8ccccc8cc7n2c46)-c2ccccc2C5(C)C)N3c2cccc3c2oc2ccccc23)cc1] 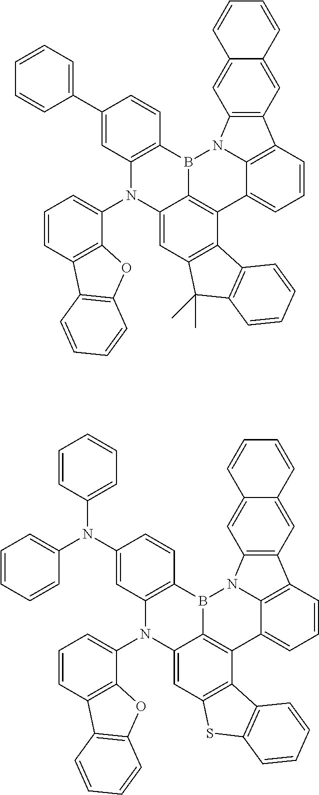 [SMILES: CC1(C)c2ccccc2-c2c1cc1c3c2-c2cccc4c5cc6ccccc6cc5n(c24)B3c2ccc(-c3ccccc3)cc2N1c1cccc2c1oc1ccccc12 ; c1ccc(N(c2ccccc2)c2ccc3c(c2)N(c2cccc4c2oc2ccccc24)c2cc4sc5ccccc5c4c4c2B3n2c3cc5ccccc5cc3c3cccc-4c32)cc1] 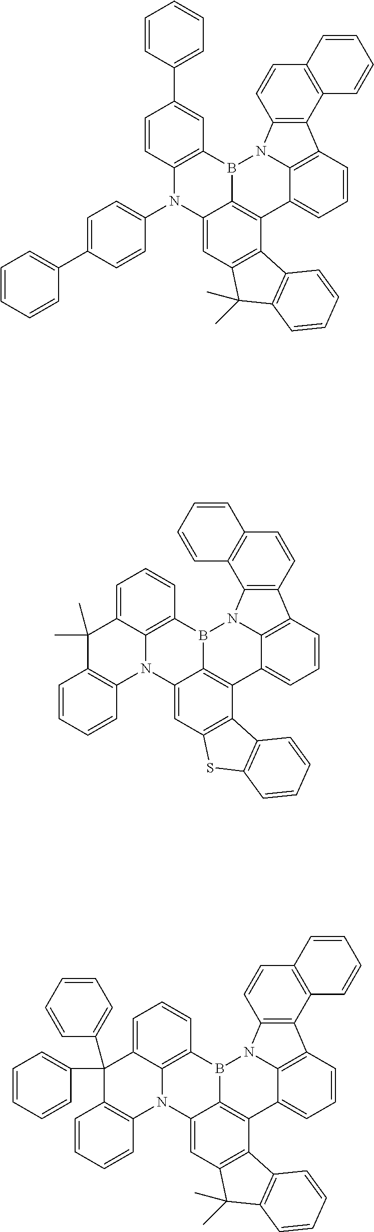 [SMILES: CC1(C)c2ccccc2-c2c1cc1c3c2-c2cccc4c5c6ccccc6ccc5n(c24)B3c2cc(-c3ccccc3)ccc2N1c1ccc(-c2ccccc2)cc1 ; CC1(C)c2ccccc2N2c3cc4sc5ccccc5c4c4c3B(c3cccc1c32)n1c2c-4cccc2c2ccc3ccccc3c21 ; CC1(C)c2ccccc2-c2c1cc1c3c2-c2cccc4c5c6ccccc6ccc5n(c24)B3c2cccc3c2N1c1ccccc1C3(c1ccccc1)c1ccccc1] 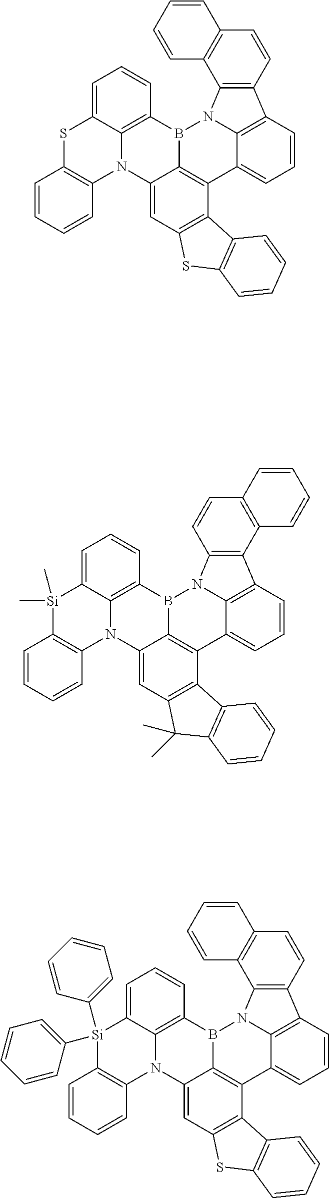 [SMILES: c1ccc2c(c1)Sc1cccc3c1N2c1cc2sc4ccccc4c2c2c1B3n1c3c-2cccc3c2ccc3ccccc3c21 ; CC1(C)c2ccccc2-c2c1cc1c3c2-c2cccc4c5c6ccccc6ccc5n(c24)B3c2cccc3c2N1c1ccccc1[Si]3(C)C ; c1ccc([Si]2(c3ccccc3)c3ccccc3N3c4cc5sc6ccccc6c5c5c4B(c4cccc2c43)n2c3c-5cccc3c3ccc4ccccc4c32)cc1] 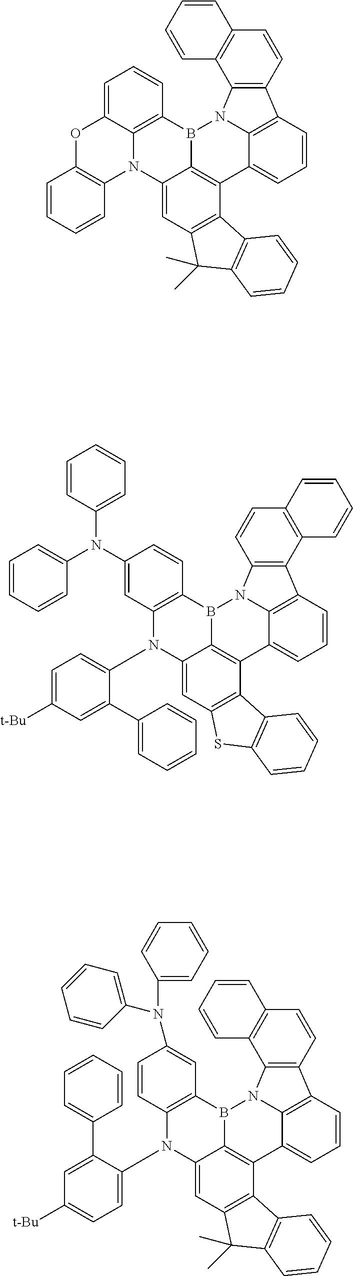 [SMILES: CC1(C)c2ccccc2-c2c1cc1c3c2-c2cccc4c5ccc6ccccc6c5n(c24)B3c2cccc3c2N1c1ccccc1O3 ; CC(C)(C)c1ccc(N2c3cc(N(c4ccccc4)c4ccccc4)ccc3B3c4c2cc2sc5ccccc5c2c4-c2cccc4c5c6ccccc6ccc5n3c24)c(-c2ccccc2)c1 ; CC(C)(C)c1ccc(N2c3ccc(N(c4ccccc4)c4ccccc4)cc3B3c4c2cc2c(c4-c4cccc5c6ccc7ccccc7c6n3c45)-c3ccccc3C2(C)C)c(-c2ccccc2)c1] 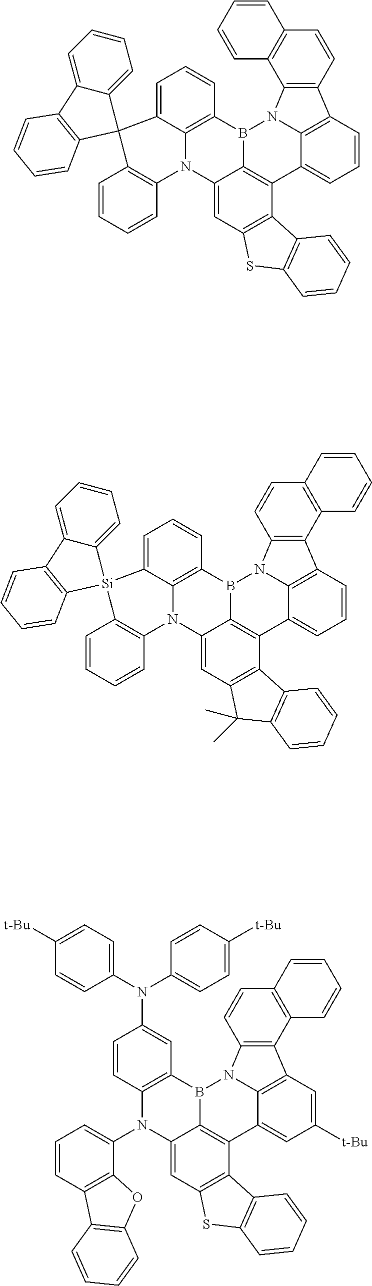 [SMILES: c1ccc2c(c1)-c1ccccc1C21c2ccccc2N2c3cc4sc5ccccc5c4c4c3B(c3cccc1c32)n1c2c-4cccc2c2ccc3ccccc3c21 ; CC1(C)c2ccccc2-c2c1cc1c3c2-c2cccc4c5c6ccccc6ccc5n(c24)B3c2cccc3c2N1c1ccccc1[Si]31c2ccccc2-c2ccccc21 ; CC(C)(C)c1ccc(N(c2ccc(C(C)(C)C)cc2)c2ccc3c(c2)B2c4c(cc5sc6ccccc6c5c4-c4cc(C(C)(C)C)cc5c6c7ccccc7ccc6n2c45)N3c2cccc3c2oc2ccccc23)cc1] 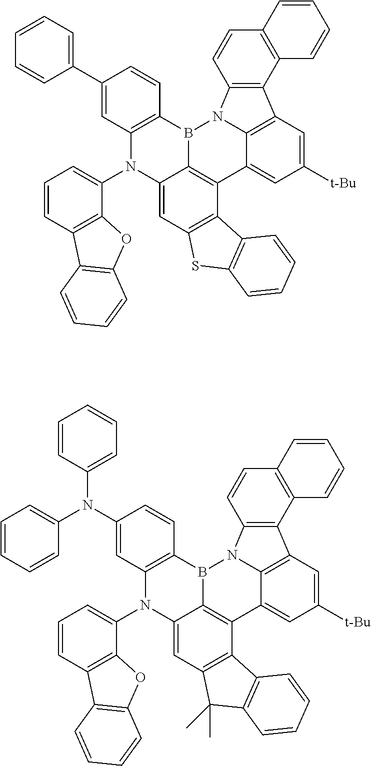 [SMILES: CC(C)(C)c1cc2c3c(c1)c1c4ccccc4ccc1n3B1c3ccc(-c4ccccc4)cc3N(c3cccc4c3oc3ccccc34)c3cc4sc5ccccc5c4c-2c31 ; CC(C)(C)c1cc2c3c(c1)c1c4ccccc4ccc1n3B1c3ccc(N(c4ccccc4)c4ccccc4)cc3N(c3cccc4c3oc3ccccc34)c3cc4c(c-2c31)-c1ccccc1C4(C)C] 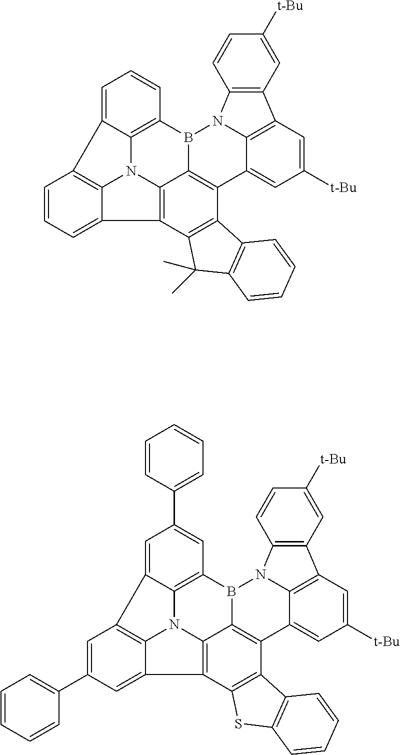 [SMILES: CC(C)(C)c1ccc2c(c1)c1cc(C(C)(C)C)cc3c1n2B1c2cccc4c5cccc6c7c8c(c-3c1c7n(c24)c56)-c1ccccc1C8(C)C ; CC(C)(C)c1ccc2c(c1)c1cc(C(C)(C)C)cc3c1n2B1c2cc(-c4ccccc4)cc4c5cc(-c6ccccc6)cc6c7c8sc9ccccc9c8c-3c1c7n(c24)c56] 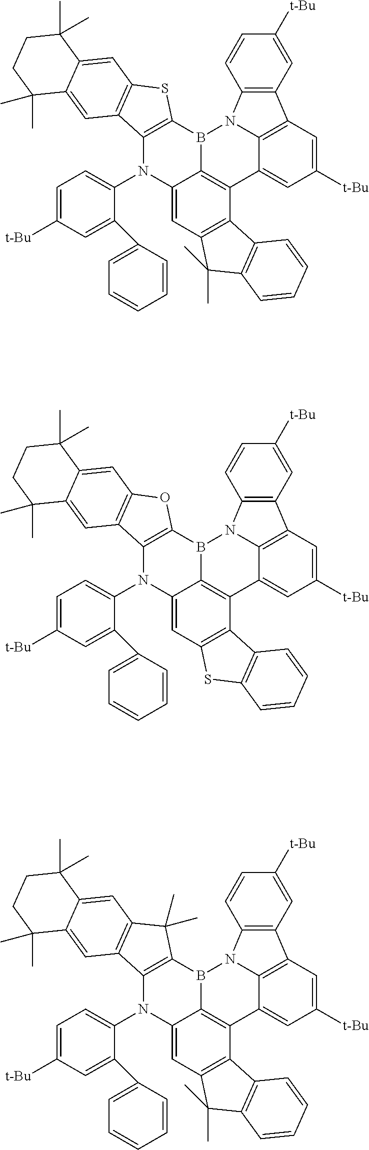 [SMILES: CC(C)(C)c1ccc(N2c3cc4c(c5c3B(c3sc6cc7c(cc6c32)C(C)(C)CCC7(C)C)n2c3ccc(C(C)(C)C)cc3c3cc(C(C)(C)C)cc-5c32)-c2ccccc2C4(C)C)c(-c2ccccc2)c1 ; CC(C)(C)c1ccc(N2c3cc4sc5ccccc5c4c4c3B(c3oc5cc6c(cc5c32)C(C)(C)CCC6(C)C)n2c3ccc(C(C)(C)C)cc3c3cc(C(C)(C)C)cc-4c32)c(-c2ccccc2)c1 ; CC(C)(C)c1ccc(N2C3=C(B4c5c2cc2c(c5-c5cc(C(C)(C)C)cc6c7cc(C(C)(C)C)ccc7n4c56)-c4ccccc4C2(C)C)C(C)(C)c2cc4c(cc23)C(C)(C)CCC4(C)C)c(-c2ccccc2)c1] 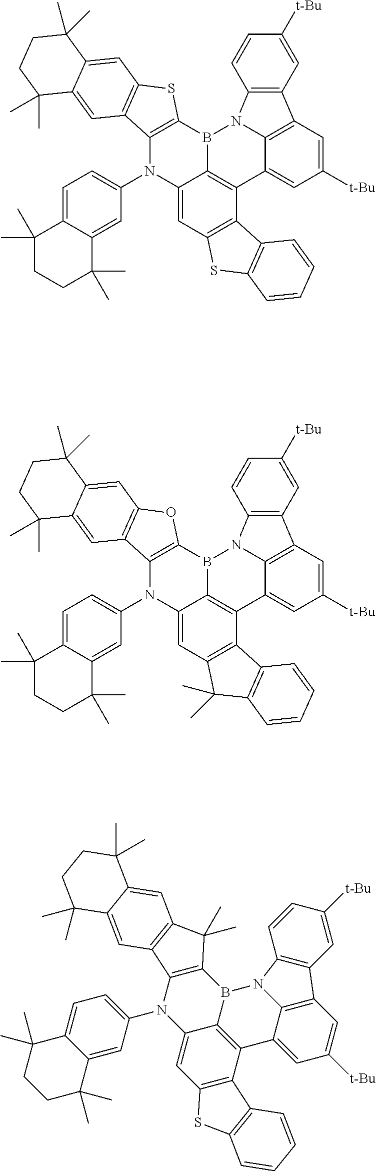 [SMILES: CC(C)(C)c1ccc2c(c1)c1cc(C(C)(C)C)cc3c1n2B1c2sc4cc5c(cc4c2N(c2ccc4c(c2)C(C)(C)CCC4(C)C)c2cc4sc6ccccc6c4c-3c21)C(C)(C)CCC5(C)C ; CC(C)(C)c1ccc2c(c1)c1cc(C(C)(C)C)cc3c1n2B1c2oc4cc5c(cc4c2N(c2ccc4c(c2)C(C)(C)CCC4(C)C)c2cc4c(c-3c21)-c1ccccc1C4(C)C)C(C)(C)CCC5(C)C ; CC(C)(C)c1ccc2c(c1)c1cc(C(C)(C)C)cc3c1n2B1C2=C(c4cc5c(cc4C2(C)C)C(C)(C)CCC5(C)C)N(c2ccc4c(c2)C(C)(C)CCC4(C)C)c2cc4sc5ccccc5c4c-3c21] 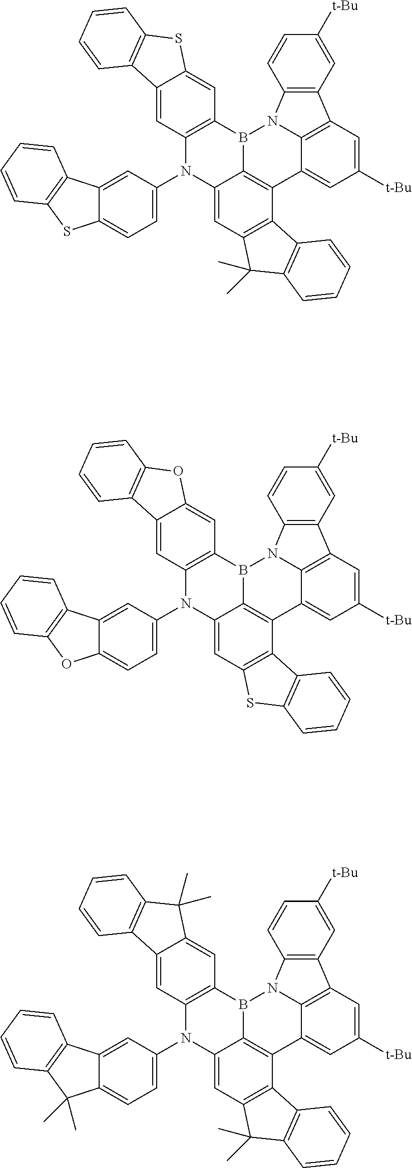 [SMILES: CC(C)(C)c1ccc2c(c1)c1cc(C(C)(C)C)cc3c1n2B1c2cc4sc5ccccc5c4cc2N(c2ccc4sc5ccccc5c4c2)c2cc4c(c-3c21)-c1ccccc1C4(C)C ; CC(C)(C)c1ccc2c(c1)c1cc(C(C)(C)C)cc3c1n2B1c2cc4oc5ccccc5c4cc2N(c2ccc4oc5ccccc5c4c2)c2cc4sc5ccccc5c4c-3c21 ; CC(C)(C)c1ccc2c(c1)c1cc(C(C)(C)C)cc3c1n2B1c2cc4c(cc2N(c2ccc5c(c2)-c2ccccc2C5(C)C)c2cc5c(c-3c21)-c1ccccc1C5(C)C)-c1ccccc1C4(C)C] 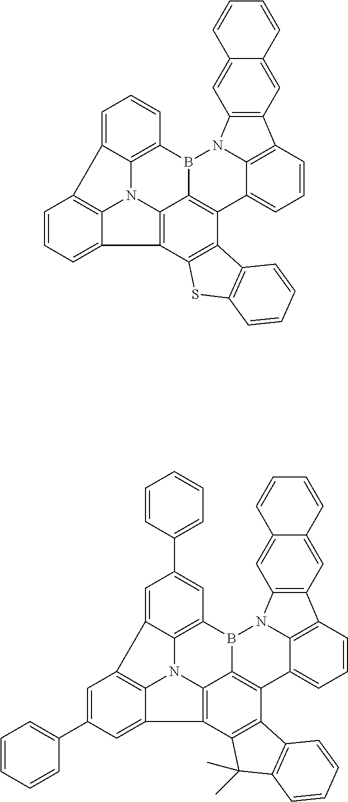 [SMILES: c1ccc2cc3c(cc2c1)c1cccc2c1n3B1c3cccc4c5cccc6c7c8sc9ccccc9c8c-2c1c7n(c34)c56 ; CC1(C)c2ccccc2-c2c3c4c5c(c21)c1cc(-c2ccccc2)cc2c6cc(-c7ccccc7)cc(c6n5c21)B4n1c2cc4ccccc4cc2c2cccc-3c21] 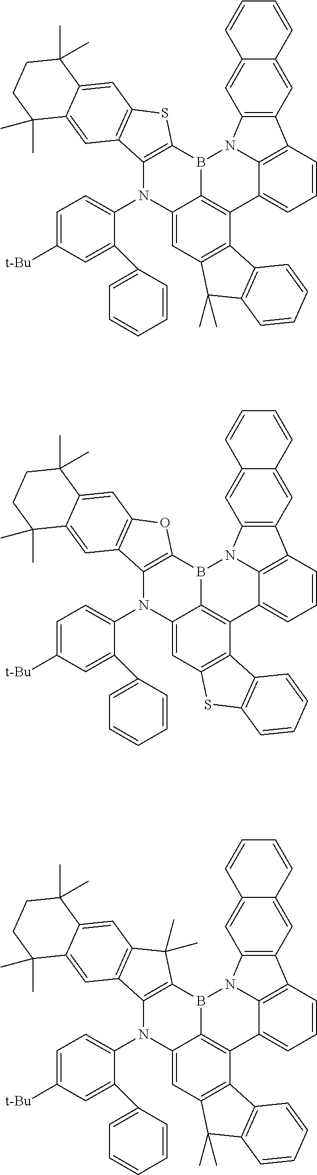 [SMILES: CC(C)(C)c1ccc(N2c3cc4c(c5c3B(c3sc6cc7c(cc6c32)C(C)(C)CCC7(C)C)n2c3cc6ccccc6cc3c3cccc-5c32)-c2ccccc2C4(C)C)c(-c2ccccc2)c1 ; CC(C)(C)c1ccc(N2c3cc4sc5ccccc5c4c4c3B(c3oc5cc6c(cc5c32)C(C)(C)CCC6(C)C)n2c3cc5ccccc5cc3c3cccc-4c32)c(-c2ccccc2)c1 ; CC(C)(C)c1ccc(N2C3=C(B4c5c2cc2c(c5-c5cccc6c7cc8ccccc8cc7n4c56)-c4ccccc4C2(C)C)C(C)(C)c2cc4c(cc23)C(C)(C)CCC4(C)C)c(-c2ccccc2)c1] 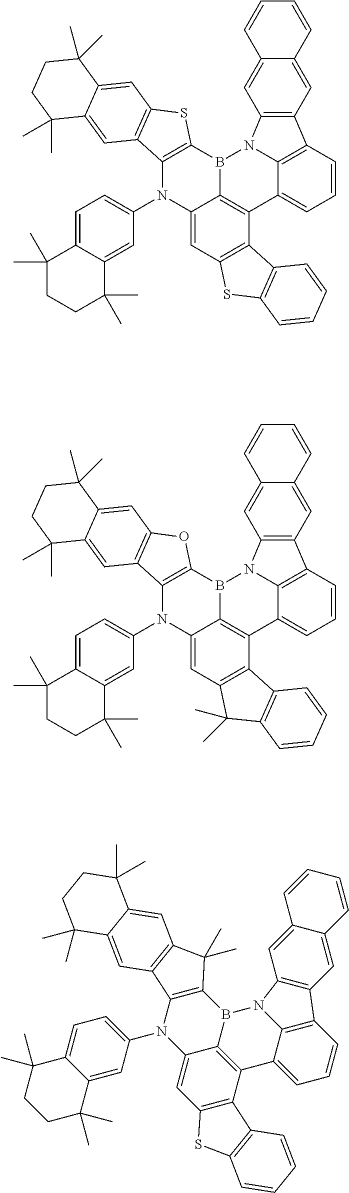 [SMILES: CC1(C)CCC(C)(C)c2cc(N3c4cc5sc6ccccc6c5c5c4B(c4sc6cc7c(cc6c43)C(C)(C)CCC7(C)C)n3c4cc6ccccc6cc4c4cccc-5c43)ccc21 ; CC1(C)CCC(C)(C)c2cc(N3c4cc5c(c6c4B(c4oc7cc8c(cc7c43)C(C)(C)CCC8(C)C)n3c4cc7ccccc7cc4c4cccc-6c43)-c3ccccc3C5(C)C)ccc21 ; CC1(C)CCC(C)(C)c2cc(N3C4=C(B5c6c3cc3sc7ccccc7c3c6-c3cccc6c7cc8ccccc8cc7n5c36)C(C)(C)c3cc5c(cc34)C(C)(C)CCC5(C)C)ccc21] 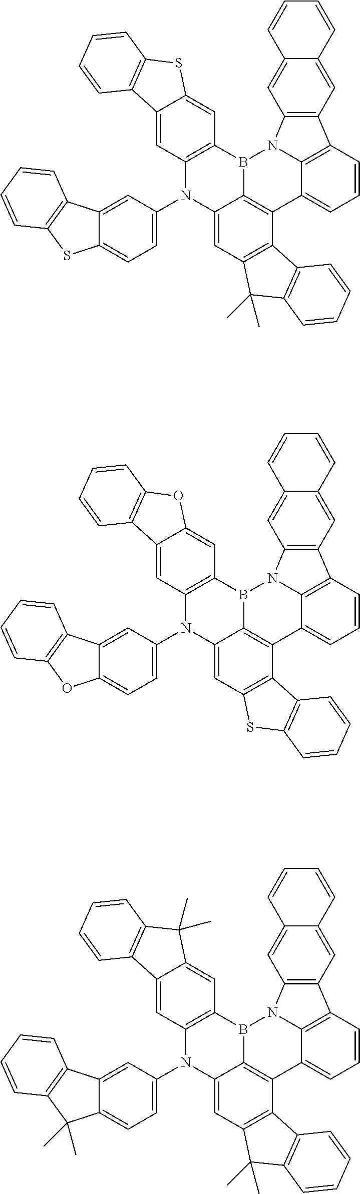 [SMILES: CC1(C)c2ccccc2-c2c1cc1c3c2-c2cccc4c5cc6ccccc6cc5n(c24)B3c2cc3sc4ccccc4c3cc2N1c1ccc2sc3ccccc3c2c1 ; c1ccc2cc3c(cc2c1)c1cccc2c1n3B1c3cc4oc5ccccc5c4cc3N(c3ccc4oc5ccccc5c4c3)c3cc4sc5ccccc5c4c-2c31 ; CC1(C)c2ccccc2-c2cc(N3c4cc5c(cc4B4c6c3cc3c(c6-c6cccc7c8cc9ccccc9cc8n4c67)-c4ccccc4C3(C)C)C(C)(C)c3ccccc3-5)ccc21] 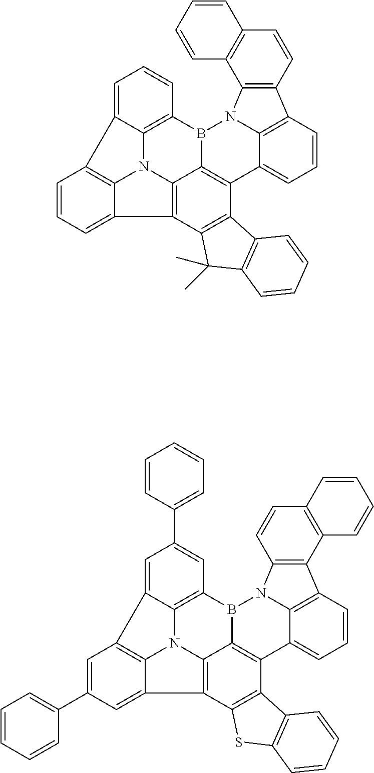 [SMILES: CC1(C)c2ccccc2-c2c3c4c5c(c21)c1cccc2c6cccc(c6n5c21)B4n1c2c-3cccc2c2ccc3ccccc3c21 ; c1ccc(-c2cc3c4c(c2)c2cc(-c5ccccc5)cc5c6c7sc8ccccc8c7c7c(c6n4c25)B3n2c3ccc4ccccc4c3c3cccc-7c32)cc1] 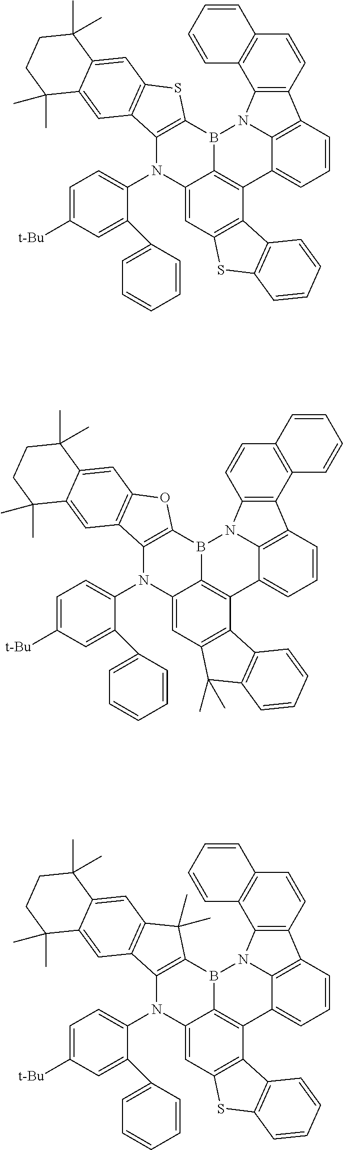 [SMILES: CC(C)(C)c1ccc(N2c3cc4sc5ccccc5c4c4c3B(c3sc5cc6c(cc5c32)C(C)(C)CCC6(C)C)n2c3c-4cccc3c3ccc4ccccc4c32)c(-c2ccccc2)c1 ; CC(C)(C)c1ccc(N2c3cc4c(c5c3B(c3oc6cc7c(cc6c32)C(C)(C)CCC7(C)C)n2c3ccc6ccccc6c3c3cccc-5c32)-c2ccccc2C4(C)C)c(-c2ccccc2)c1 ; CC(C)(C)c1ccc(N2C3=C(B4c5c2cc2sc6ccccc6c2c5-c2cccc5c6ccc7ccccc7c6n4c25)C(C)(C)c2cc4c(cc23)C(C)(C)CCC4(C)C)c(-c2ccccc2)c1] 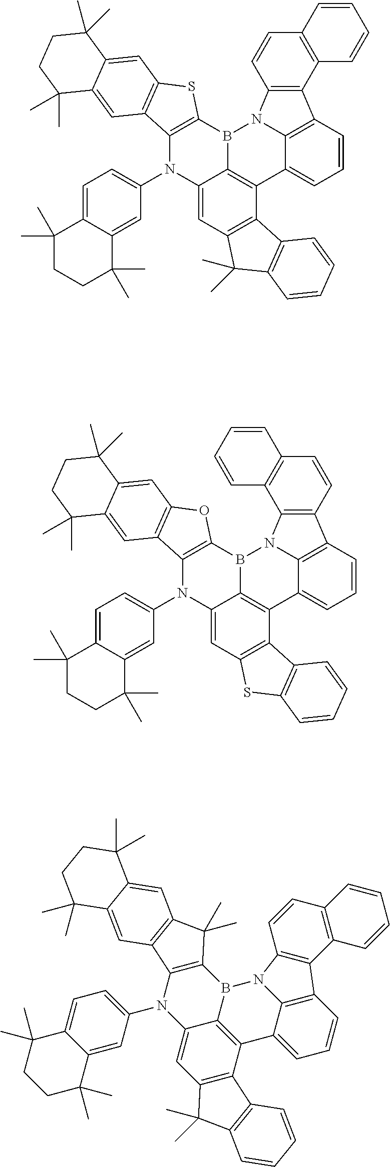 [SMILES: CC1(C)CCC(C)(C)c2cc(N3c4cc5c(c6c4B(c4sc7cc8c(cc7c43)C(C)(C)CCC8(C)C)n3c4ccc7ccccc7c4c4cccc-6c43)-c3ccccc3C5(C)C)ccc21 ; CC1(C)CCC(C)(C)c2cc(N3c4cc5sc6ccccc6c5c5c4B(c4oc6cc7c(cc6c43)C(C)(C)CCC7(C)C)n3c4c-5cccc4c4ccc5ccccc5c43)ccc21 ; CC1(C)CCC(C)(C)c2cc(N3C4=C(B5c6c3cc3c(c6-c6cccc7c8c9ccccc9ccc8n5c67)-c5ccccc5C3(C)C)C(C)(C)c3cc5c(cc34)C(C)(C)CCC5(C)C)ccc21] 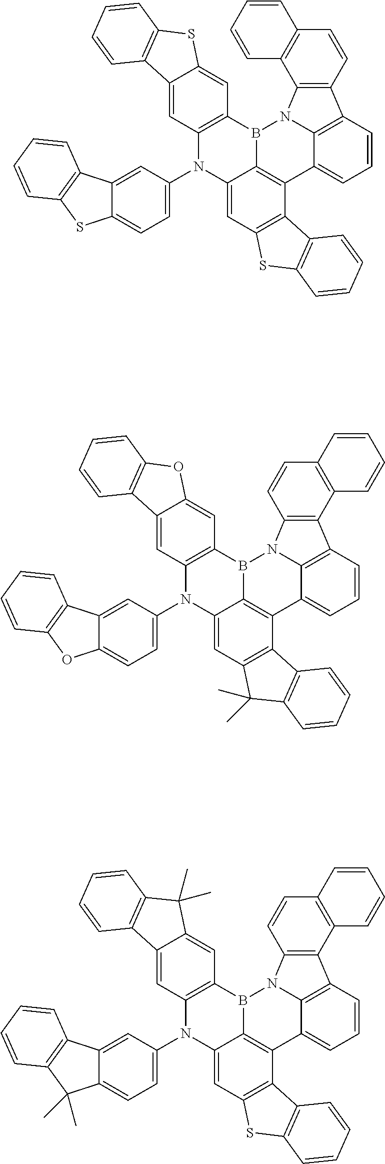 [SMILES: c1ccc2c(c1)ccc1c3cccc4c3n(c21)B1c2cc3sc5ccccc5c3cc2N(c2ccc3sc5ccccc5c3c2)c2cc3sc5ccccc5c3c-4c21 ; CC1(C)c2ccccc2-c2c1cc1c3c2-c2cccc4c5c6ccccc6ccc5n(c24)B3c2cc3oc4ccccc4c3cc2N1c1ccc2oc3ccccc3c2c1 ; CC1(C)c2ccccc2-c2cc(N3c4cc5c(cc4B4c6c3cc3sc7ccccc7c3c6-c3cccc6c7c8ccccc8ccc7n4c36)C(C)(C)c3ccccc3-5)ccc21] 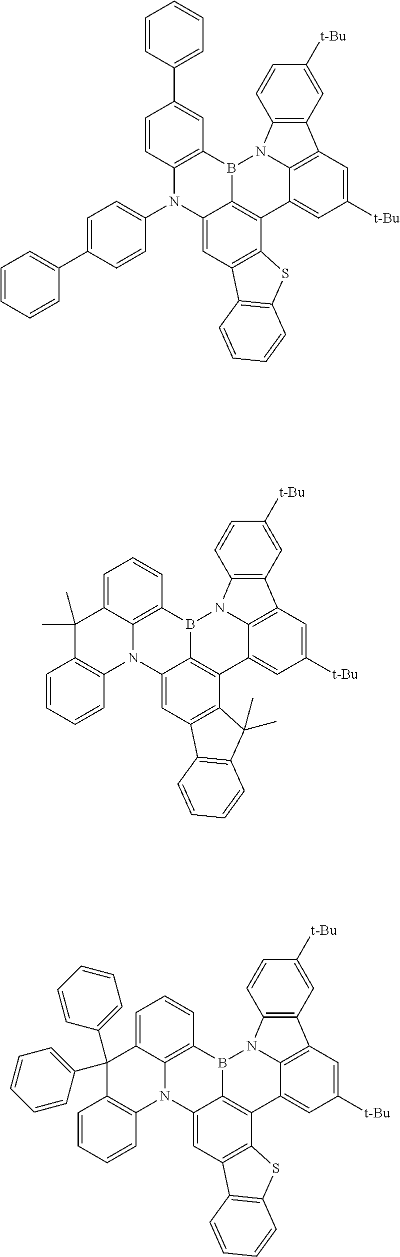 [SMILES: CC(C)(C)c1ccc2c(c1)c1cc(C(C)(C)C)cc3c1n2B1c2cc(-c4ccccc4)ccc2N(c2ccc(-c4ccccc4)cc2)c2cc4c(sc5ccccc54)c-3c21 ; CC(C)(C)c1ccc2c(c1)c1cc(C(C)(C)C)cc3c1n2B1c2cccc4c2N(c2ccccc2C4(C)C)c2cc4c(c-3c21)C(C)(C)c1ccccc1-4 ; CC(C)(C)c1ccc2c(c1)c1cc(C(C)(C)C)cc3c1n2B1c2cccc4c2N(c2ccccc2C4(c2ccccc2)c2ccccc2)c2cc4c(sc5ccccc54)c-3c21] 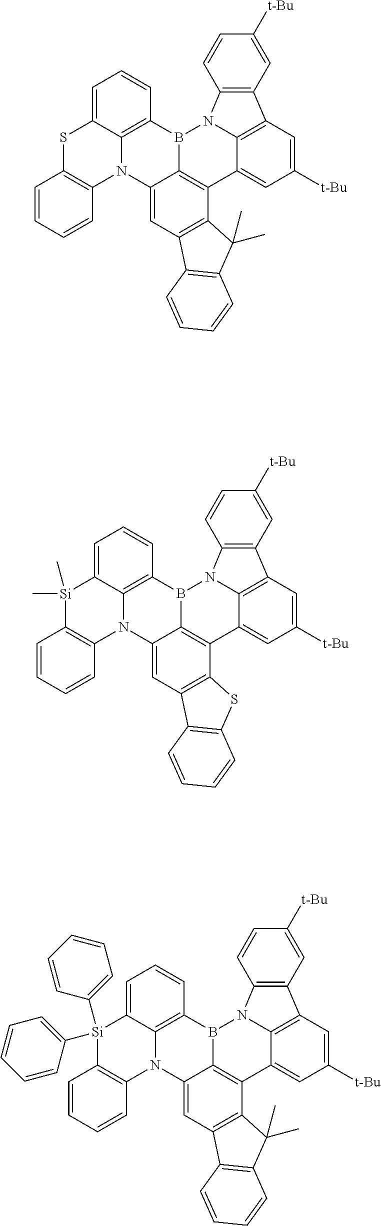 [SMILES: CC(C)(C)c1ccc2c(c1)c1cc(C(C)(C)C)cc3c1n2B1c2cccc4c2N(c2ccccc2S4)c2cc4c(c-3c21)C(C)(C)c1ccccc1-4 ; CC(C)(C)c1ccc2c(c1)c1cc(C(C)(C)C)cc3c1n2B1c2cccc4c2N(c2ccccc2[Si]4(C)C)c2cc4c(sc5ccccc54)c-3c21 ; CC(C)(C)c1ccc2c(c1)c1cc(C(C)(C)C)cc3c1n2B1c2cccc4c2N(c2ccccc2[Si]4(c2ccccc2)c2ccccc2)c2cc4c(c-3c21)C(C)(C)c1ccccc1-4] 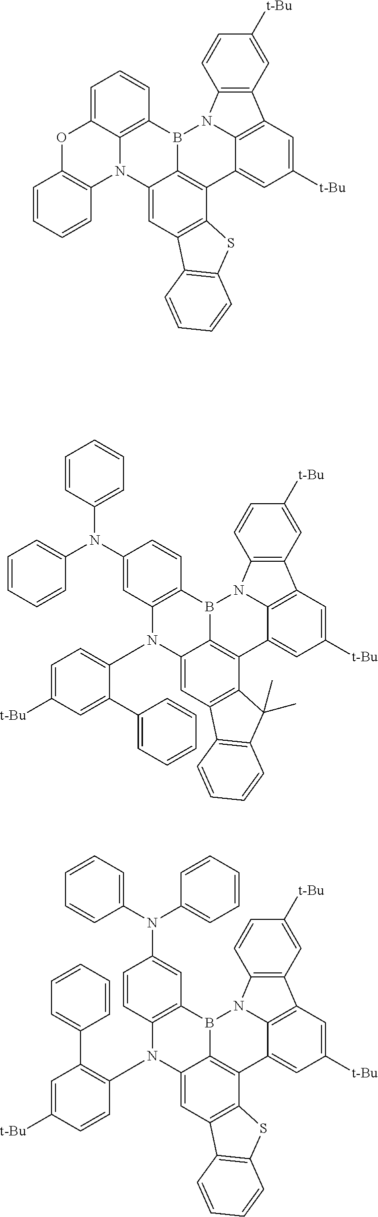 [SMILES: CC(C)(C)c1ccc2c(c1)c1cc(C(C)(C)C)cc3c1n2B1c2cccc4c2N(c2ccccc2O4)c2cc4c(sc5ccccc54)c-3c21 ; CC(C)(C)c1ccc(N2c3cc(N(c4ccccc4)c4ccccc4)ccc3B3c4c2cc2c(c4-c4cc(C(C)(C)C)cc5c6cc(C(C)(C)C)ccc6n3c45)C(C)(C)c3ccccc3-2)c(-c2ccccc2)c1 ; CC(C)(C)c1ccc(N2c3ccc(N(c4ccccc4)c4ccccc4)cc3B3c4c2cc2c(sc5ccccc52)c4-c2cc(C(C)(C)C)cc4c5cc(C(C)(C)C)ccc5n3c24)c(-c2ccccc2)c1] 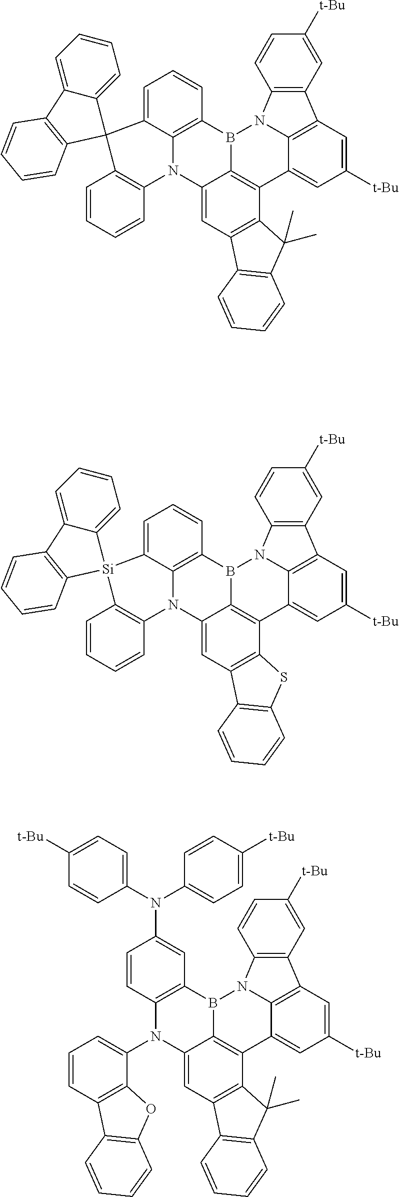 [SMILES: CC(C)(C)c1ccc2c(c1)c1cc(C(C)(C)C)cc3c1n2B1c2cccc4c2N(c2ccccc2C42c4ccccc4-c4ccccc42)c2cc4c(c-3c21)C(C)(C)c1ccccc1-4 ; CC(C)(C)c1ccc2c(c1)c1cc(C(C)(C)C)cc3c1n2B1c2cccc4c2N(c2ccccc2[Si]42c4ccccc4-c4ccccc42)c2cc4c(sc5ccccc54)c-3c21 ; CC(C)(C)c1ccc(N(c2ccc(C(C)(C)C)cc2)c2ccc3c(c2)B2c4c(cc5c(c4-c4cc(C(C)(C)C)cc6c7cc(C(C)(C)C)ccc7n2c46)C(C)(C)c2ccccc2-5)N3c2cccc3c2oc2ccccc23)cc1] 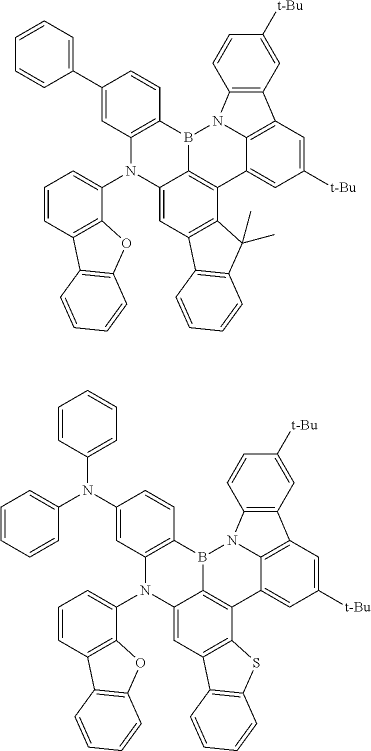 [SMILES: CC(C)(C)c1ccc2c(c1)c1cc(C(C)(C)C)cc3c1n2B1c2ccc(-c4ccccc4)cc2N(c2cccc4c2oc2ccccc24)c2cc4c(c-3c21)C(C)(C)c1ccccc1-4 ; CC(C)(C)c1ccc2c(c1)c1cc(C(C)(C)C)cc3c1n2B1c2ccc(N(c4ccccc4)c4ccccc4)cc2N(c2cccc4c2oc2ccccc24)c2cc4c(sc5ccccc54)c-3c21] 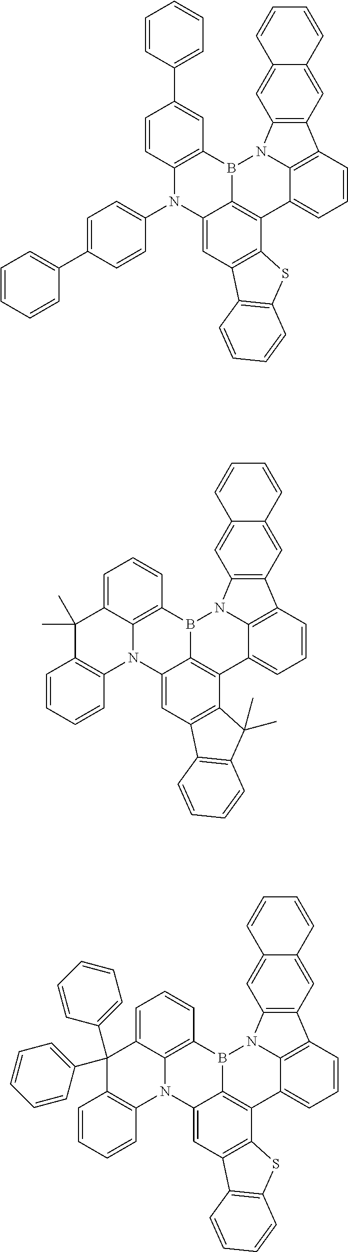 [SMILES: c1ccc(-c2ccc(N3c4ccc(-c5ccccc5)cc4B4c5c3cc3c(sc6ccccc63)c5-c3cccc5c6cc7ccccc7cc6n4c35)cc2)cc1 ; CC1(C)c2ccccc2N2c3cc4c(c5c3B(c3cccc1c32)n1c2cc3ccccc3cc2c2cccc-5c21)C(C)(C)c1ccccc1-4 ; c1ccc(C2(c3ccccc3)c3ccccc3N3c4cc5c(sc6ccccc65)c5c4B(c4cccc2c43)n2c3cc4ccccc4cc3c3cccc-5c32)cc1] 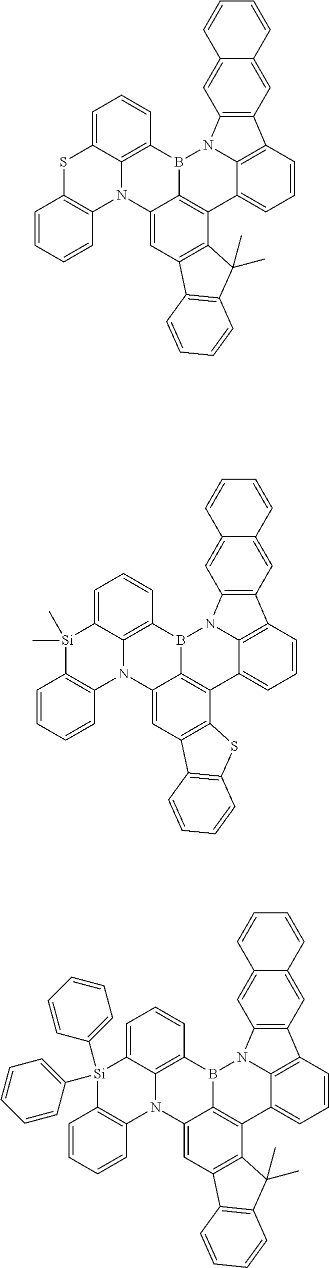 [SMILES: CC1(C)c2ccccc2-c2cc3c4c(c21)-c1cccc2c5cc6ccccc6cc5n(c12)B4c1cccc2c1N3c1ccccc1S2 ; C[Si]1(C)c2ccccc2N2c3cc4c(sc5ccccc54)c4c3B(c3cccc1c32)n1c2cc3ccccc3cc2c2cccc-4c21 ; CC1(C)c2ccccc2-c2cc3c4c(c21)-c1cccc2c5cc6ccccc6cc5n(c12)B4c1cccc2c1N3c1ccccc1[Si]2(c1ccccc1)c1ccccc1] 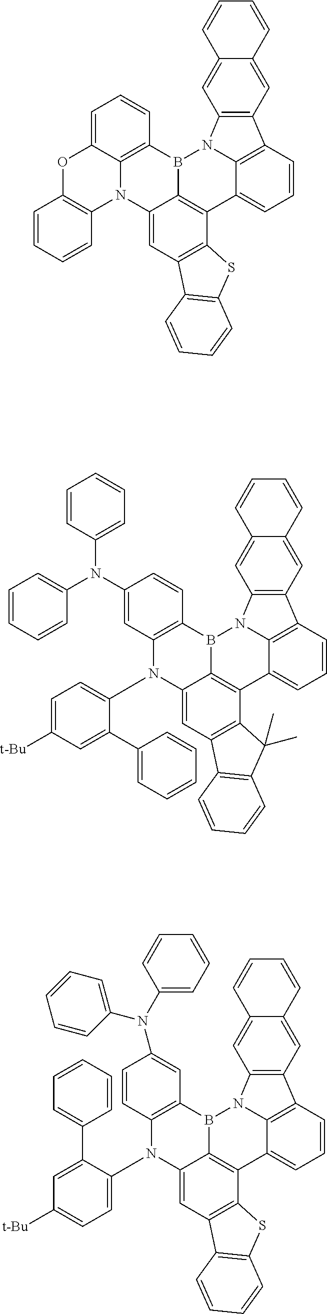 [SMILES: c1ccc2c(c1)Oc1cccc3c1N2c1cc2c(sc4ccccc42)c2c1B3n1c3cc4ccccc4cc3c3cccc-2c31 ; CC(C)(C)c1ccc(N2c3cc(N(c4ccccc4)c4ccccc4)ccc3B3c4c2cc2c(c4-c4cccc5c6cc7ccccc7cc6n3c45)C(C)(C)c3ccccc3-2)c(-c2ccccc2)c1 ; CC(C)(C)c1ccc(N2c3ccc(N(c4ccccc4)c4ccccc4)cc3B3c4c2cc2c(sc5ccccc52)c4-c2cccc4c5cc6ccccc6cc5n3c24)c(-c2ccccc2)c1] 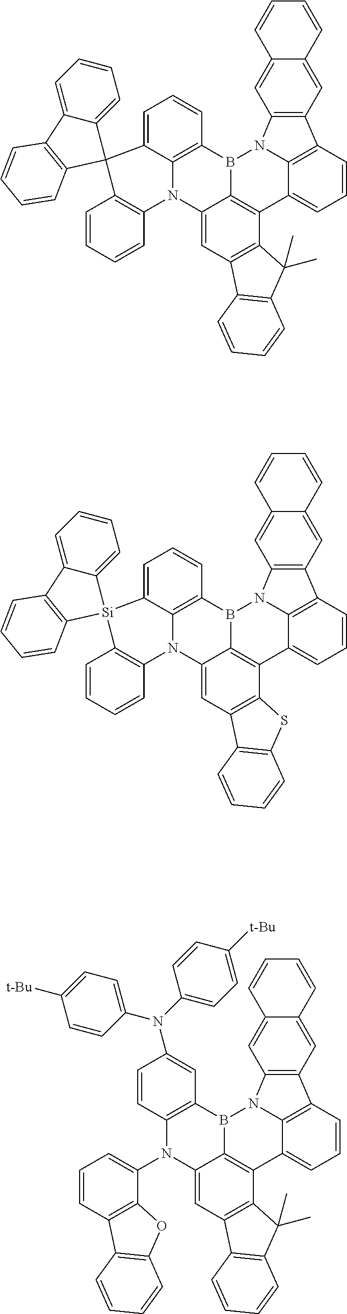 [SMILES: CC1(C)c2ccccc2-c2cc3c4c(c21)-c1cccc2c5cc6ccccc6cc5n(c12)B4c1cccc2c1N3c1ccccc1C21c2ccccc2-c2ccccc21 ; c1ccc2c(c1)-c1ccccc1[Si]21c2ccccc2N2c3cc4c(sc5ccccc54)c4c3B(c3cccc1c32)n1c2cc3ccccc3cc2c2cccc-4c21 ; CC(C)(C)c1ccc(N(c2ccc(C(C)(C)C)cc2)c2ccc3c(c2)B2c4c(cc5c(c4-c4cccc6c7cc8ccccc8cc7n2c46)C(C)(C)c2ccccc2-5)N3c2cccc3c2oc2ccccc23)cc1] 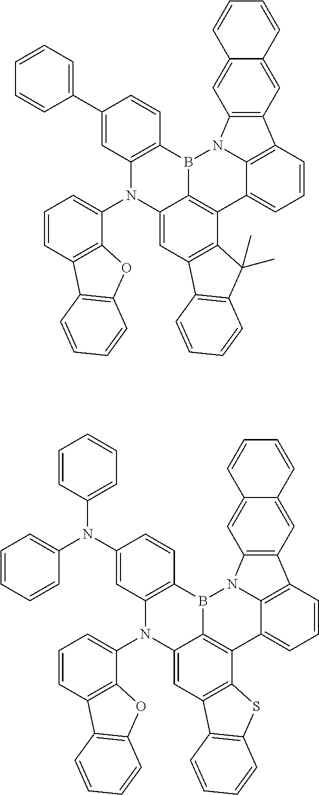 [SMILES: CC1(C)c2ccccc2-c2cc3c4c(c21)-c1cccc2c5cc6ccccc6cc5n(c12)B4c1ccc(-c2ccccc2)cc1N3c1cccc2c1oc1ccccc12 ; c1ccc(N(c2ccccc2)c2ccc3c(c2)N(c2cccc4c2oc2ccccc24)c2cc4c(sc5ccccc54)c4c2B3n2c3cc5ccccc5cc3c3cccc-4c32)cc1] 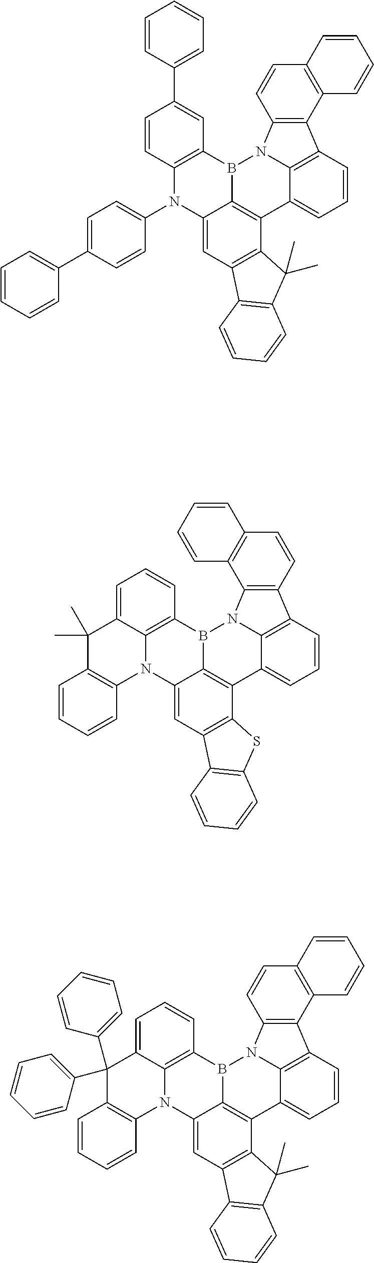 [SMILES: CC1(C)c2ccccc2-c2cc3c4c(c21)-c1cccc2c5c6ccccc6ccc5n(c12)B4c1cc(-c2ccccc2)ccc1N3c1ccc(-c2ccccc2)cc1 ; CC1(C)c2ccccc2N2c3cc4c(sc5ccccc54)c4c3B(c3cccc1c32)n1c2c-4cccc2c2ccc3ccccc3c21 ; CC1(C)c2ccccc2-c2cc3c4c(c21)-c1cccc2c5c6ccccc6ccc5n(c12)B4c1cccc2c1N3c1ccccc1C2(c1ccccc1)c1ccccc1] 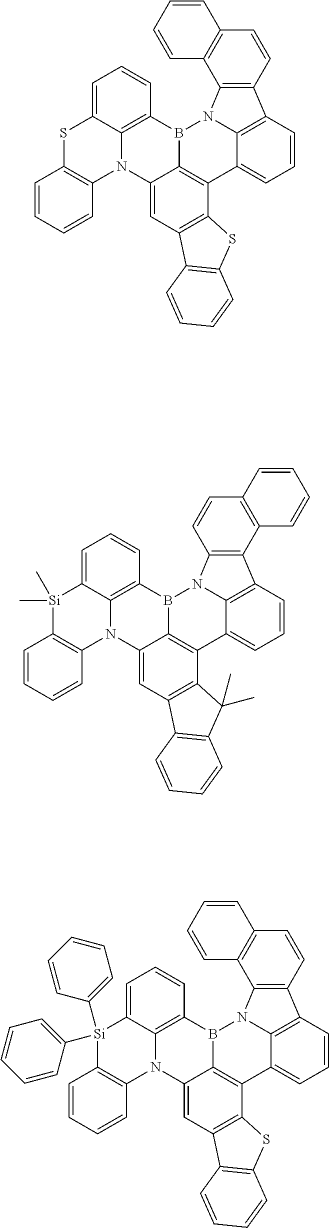 [SMILES: c1ccc2c(c1)Sc1cccc3c1N2c1cc2c(sc4ccccc42)c2c1B3n1c3c-2cccc3c2ccc3ccccc3c21 ; CC1(C)c2ccccc2-c2cc3c4c(c21)-c1cccc2c5c6ccccc6ccc5n(c12)B4c1cccc2c1N3c1ccccc1[Si]2(C)C ; c1ccc([Si]2(c3ccccc3)c3ccccc3N3c4cc5c(sc6ccccc65)c5c4B(c4cccc2c43)n2c3c-5cccc3c3ccc4ccccc4c32)cc1] 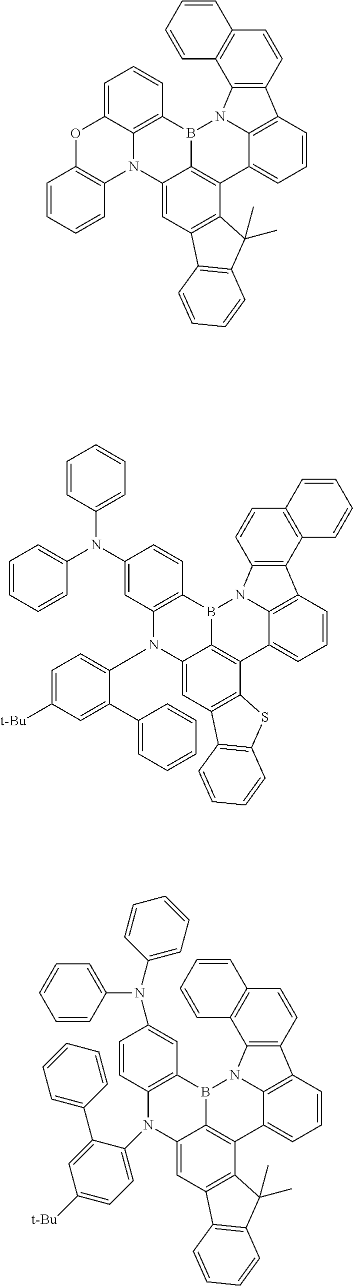 [SMILES: CC1(C)c2ccccc2-c2cc3c4c(c21)-c1cccc2c5ccc6ccccc6c5n(c12)B4c1cccc2c1N3c1ccccc1O2 ; CC(C)(C)c1ccc(N2c3cc(N(c4ccccc4)c4ccccc4)ccc3B3c4c2cc2c(sc5ccccc52)c4-c2cccc4c5c6ccccc6ccc5n3c24)c(-c2ccccc2)c1 ; CC(C)(C)c1ccc(N2c3ccc(N(c4ccccc4)c4ccccc4)cc3B3c4c2cc2c(c4-c4cccc5c6ccc7ccccc7c6n3c45)C(C)(C)c3ccccc3-2)c(-c2ccccc2)c1] 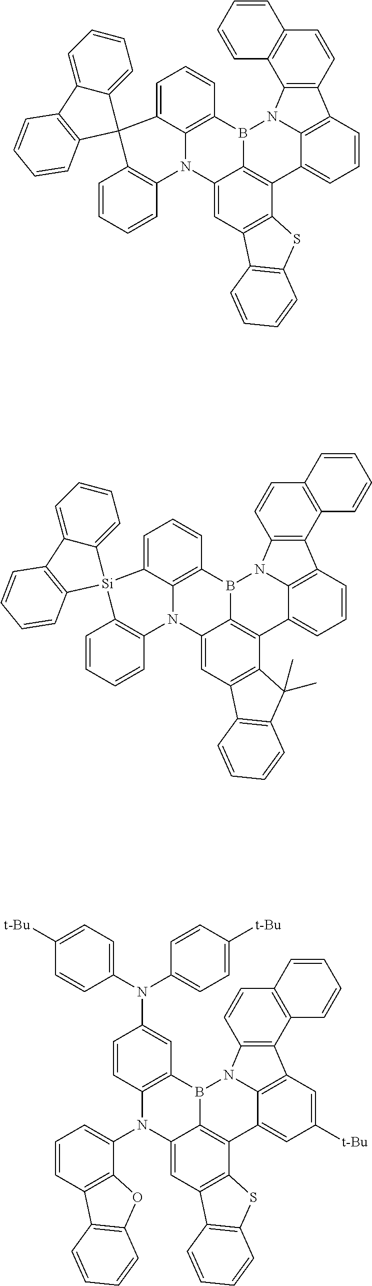 [SMILES: c1ccc2c(c1)-c1ccccc1C21c2ccccc2N2c3cc4c(sc5ccccc54)c4c3B(c3cccc1c32)n1c2c-4cccc2c2ccc3ccccc3c21 ; CC1(C)c2ccccc2-c2cc3c4c(c21)-c1cccc2c5c6ccccc6ccc5n(c12)B4c1cccc2c1N3c1ccccc1[Si]21c2ccccc2-c2ccccc21 ; CC(C)(C)c1ccc(N(c2ccc(C(C)(C)C)cc2)c2ccc3c(c2)B2c4c(cc5c(sc6ccccc65)c4-c4cc(C(C)(C)C)cc5c6c7ccccc7ccc6n2c45)N3c2cccc3c2oc2ccccc23)cc1] 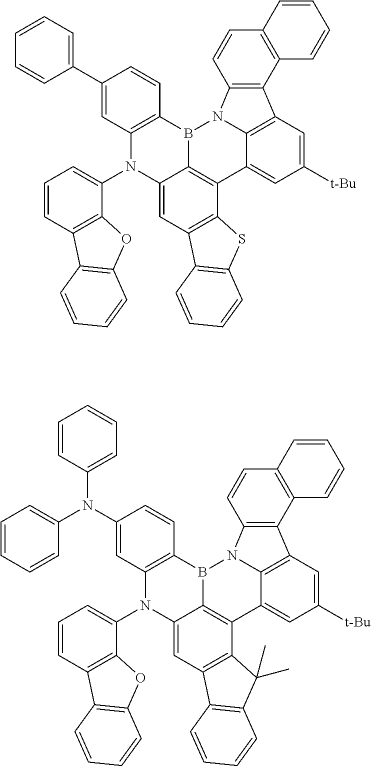 [SMILES: CC(C)(C)c1cc2c3c(c1)c1c4ccccc4ccc1n3B1c3ccc(-c4ccccc4)cc3N(c3cccc4c3oc3ccccc34)c3cc4c(sc5ccccc54)c-2c31 ; CC(C)(C)c1cc2c3c(c1)c1c4ccccc4ccc1n3B1c3ccc(N(c4ccccc4)c4ccccc4)cc3N(c3cccc4c3oc3ccccc34)c3cc4c(c-2c31)C(C)(C)c1ccccc1-4] 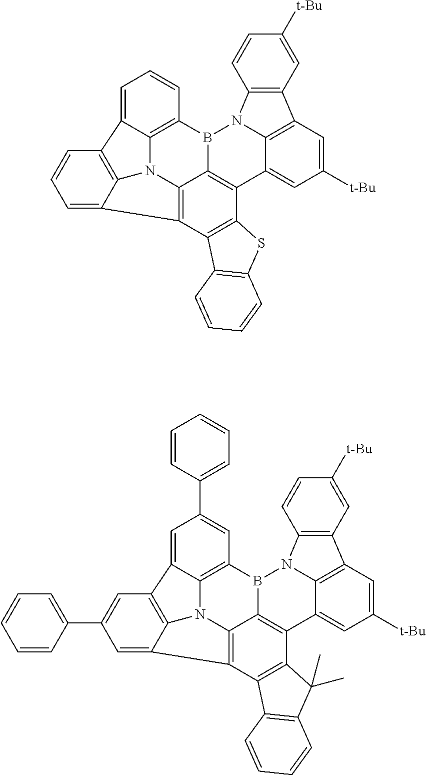 [SMILES: CC(C)(C)c1ccc2c(c1)c1cc(C(C)(C)C)cc3c1n2B1c2cccc4c5cccc6c7c8c(sc9ccccc98)c-3c1c7n(c24)c56 ; CC(C)(C)c1ccc2c(c1)c1cc(C(C)(C)C)cc3c1n2B1c2cc(-c4ccccc4)cc4c5cc(-c6ccccc6)cc6c7c8c(c-3c1c7n(c24)c56)C(C)(C)c1ccccc1-8] 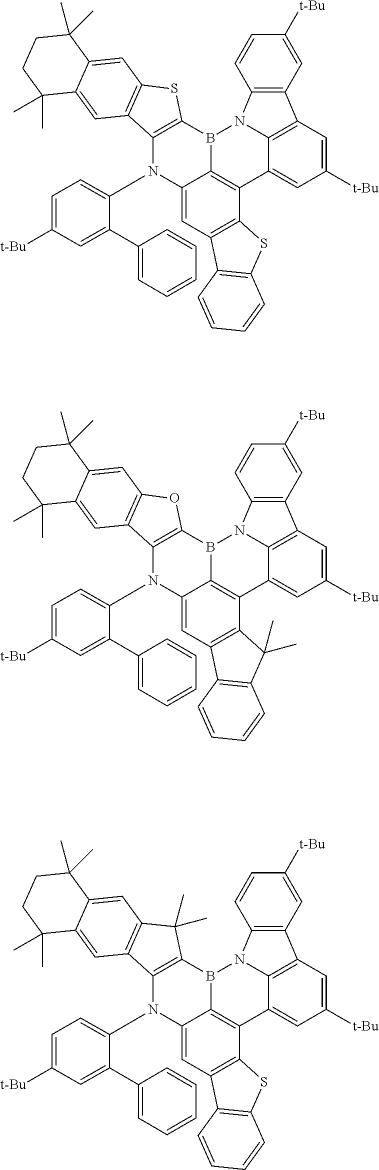 [SMILES: CC(C)(C)c1ccc(N2c3cc4c(sc5ccccc54)c4c3B(c3sc5cc6c(cc5c32)C(C)(C)CCC6(C)C)n2c3ccc(C(C)(C)C)cc3c3cc(C(C)(C)C)cc-4c32)c(-c2ccccc2)c1 ; CC(C)(C)c1ccc(N2c3cc4c(c5c3B(c3oc6cc7c(cc6c32)C(C)(C)CCC7(C)C)n2c3ccc(C(C)(C)C)cc3c3cc(C(C)(C)C)cc-5c32)C(C)(C)c2ccccc2-4)c(-c2ccccc2)c1 ; CC(C)(C)c1ccc(N2C3=C(B4c5c2cc2c(sc6ccccc62)c5-c2cc(C(C)(C)C)cc5c6cc(C(C)(C)C)ccc6n4c25)C(C)(C)c2cc4c(cc23)C(C)(C)CCC4(C)C)c(-c2ccccc2)c1] 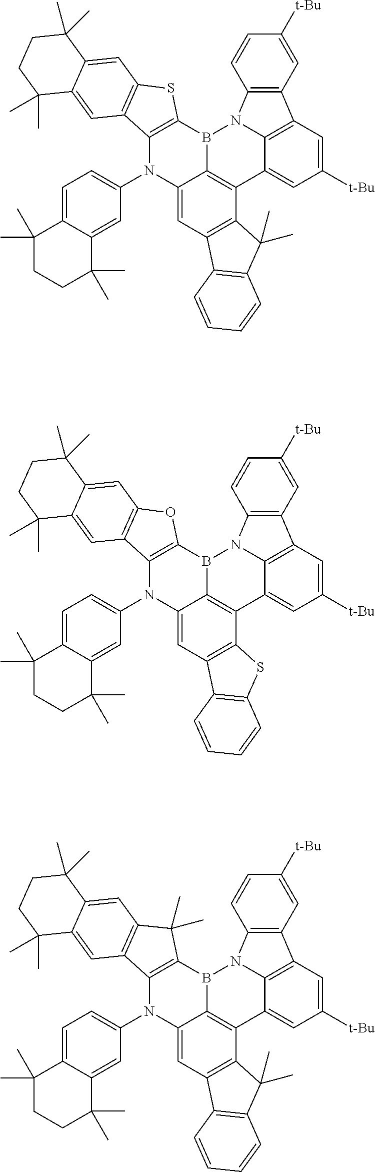 [SMILES: CC(C)(C)c1ccc2c(c1)c1cc(C(C)(C)C)cc3c1n2B1c2sc4cc5c(cc4c2N(c2ccc4c(c2)C(C)(C)CCC4(C)C)c2cc4c(c-3c21)C(C)(C)c1ccccc1-4)C(C)(C)CCC5(C)C ; CC(C)(C)c1ccc2c(c1)c1cc(C(C)(C)C)cc3c1n2B1c2oc4cc5c(cc4c2N(c2ccc4c(c2)C(C)(C)CCC4(C)C)c2cc4c(sc6ccccc64)c-3c21)C(C)(C)CCC5(C)C ; CC(C)(C)c1ccc2c(c1)c1cc(C(C)(C)C)cc3c1n2B1C2=C(c4cc5c(cc4C2(C)C)C(C)(C)CCC5(C)C)N(c2ccc4c(c2)C(C)(C)CCC4(C)C)c2cc4c(c-3c21)C(C)(C)c1ccccc1-4] 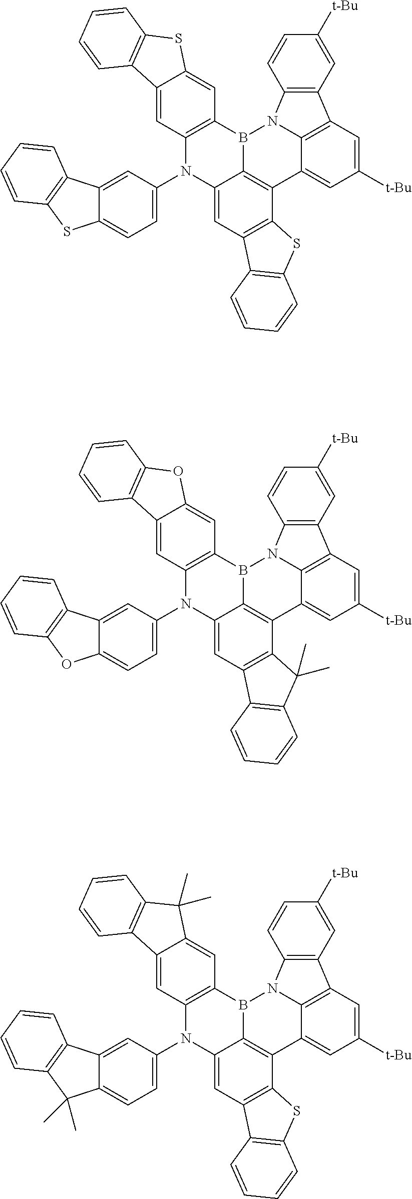 [SMILES: CC(C)(C)c1ccc2c(c1)c1cc(C(C)(C)C)cc3c1n2B1c2cc4sc5ccccc5c4cc2N(c2ccc4sc5ccccc5c4c2)c2cc4c(sc5ccccc54)c-3c21 ; CC(C)(C)c1ccc2c(c1)c1cc(C(C)(C)C)cc3c1n2B1c2cc4oc5ccccc5c4cc2N(c2ccc4oc5ccccc5c4c2)c2cc4c(c-3c21)C(C)(C)c1ccccc1-4 ; CC(C)(C)c1ccc2c(c1)c1cc(C(C)(C)C)cc3c1n2B1c2cc4c(cc2N(c2ccc5c(c2)-c2ccccc2C5(C)C)c2cc5c(sc6ccccc65)c-3c21)-c1ccccc1C4(C)C] 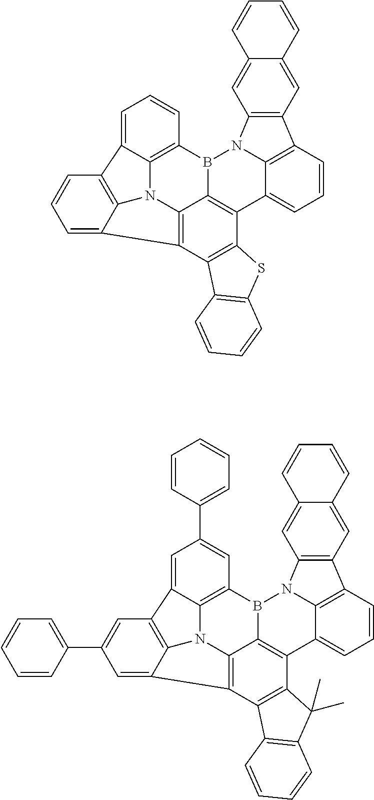 [SMILES: c1ccc2cc3c(cc2c1)c1cccc2c1n3B1c3cccc4c5cccc6c7c8c(sc9ccccc98)c-2c1c7n(c34)c56 ; CC1(C)c2ccccc2-c2c1c1c3c4c2c2cc(-c5ccccc5)cc5c6cc(-c7ccccc7)cc(c6n4c52)B3n2c3cc4ccccc4cc3c3cccc-1c32] 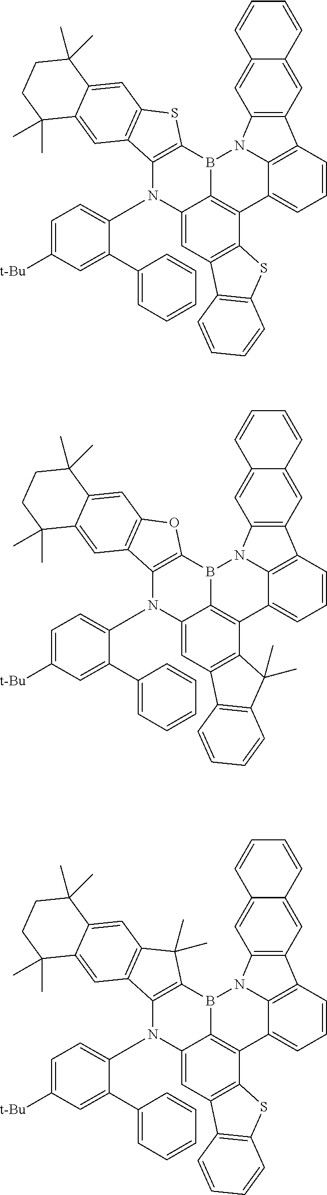 [SMILES: CC(C)(C)c1ccc(N2c3cc4c(sc5ccccc54)c4c3B(c3sc5cc6c(cc5c32)C(C)(C)CCC6(C)C)n2c3cc5ccccc5cc3c3cccc-4c32)c(-c2ccccc2)c1 ; CC(C)(C)c1ccc(N2c3cc4c(c5c3B(c3oc6cc7c(cc6c32)C(C)(C)CCC7(C)C)n2c3cc6ccccc6cc3c3cccc-5c32)C(C)(C)c2ccccc2-4)c(-c2ccccc2)c1 ; CC(C)(C)c1ccc(N2C3=C(B4c5c2cc2c(sc6ccccc62)c5-c2cccc5c6cc7ccccc7cc6n4c25)C(C)(C)c2cc4c(cc23)C(C)(C)CCC4(C)C)c(-c2ccccc2)c1] 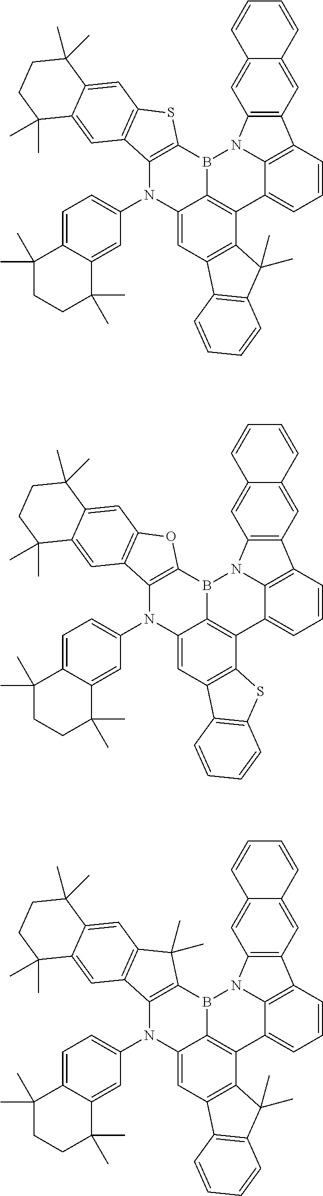 [SMILES: CC1(C)CCC(C)(C)c2cc(N3c4cc5c(c6c4B(c4sc7cc8c(cc7c43)C(C)(C)CCC8(C)C)n3c4cc7ccccc7cc4c4cccc-6c43)C(C)(C)c3ccccc3-5)ccc21 ; CC1(C)CCC(C)(C)c2cc(N3c4cc5c(sc6ccccc65)c5c4B(c4oc6cc7c(cc6c43)C(C)(C)CCC7(C)C)n3c4cc6ccccc6cc4c4cccc-5c43)ccc21 ; CC1(C)CCC(C)(C)c2cc(N3C4=C(B5c6c3cc3c(c6-c6cccc7c8cc9ccccc9cc8n5c67)C(C)(C)c5ccccc5-3)C(C)(C)c3cc5c(cc34)C(C)(C)CCC5(C)C)ccc21] 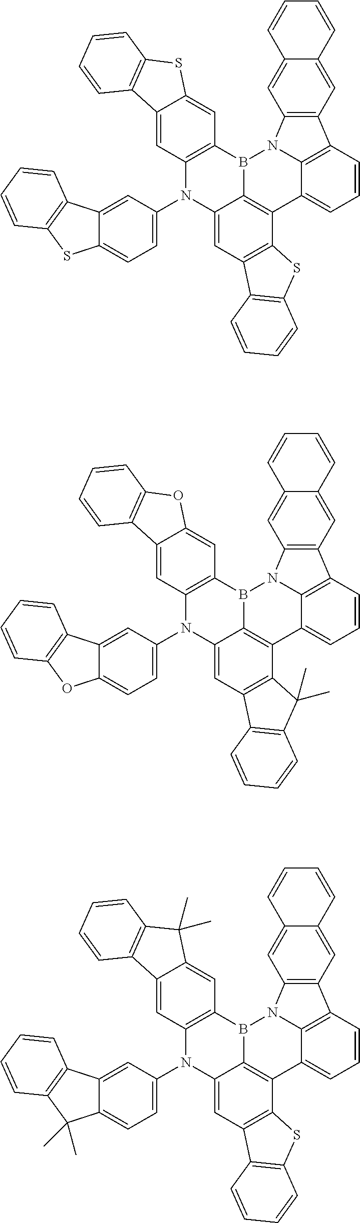 [SMILES: c1ccc2cc3c(cc2c1)c1cccc2c1n3B1c3cc4sc5ccccc5c4cc3N(c3ccc4sc5ccccc5c4c3)c3cc4c(sc5ccccc54)c-2c31 ; CC1(C)c2ccccc2-c2cc3c4c(c21)-c1cccc2c5cc6ccccc6cc5n(c12)B4c1cc2oc4ccccc4c2cc1N3c1ccc2oc3ccccc3c2c1 ; CC1(C)c2ccccc2-c2cc(N3c4cc5c(cc4B4c6c3cc3c(sc7ccccc73)c6-c3cccc6c7cc8ccccc8cc7n4c36)C(C)(C)c3ccccc3-5)ccc21] 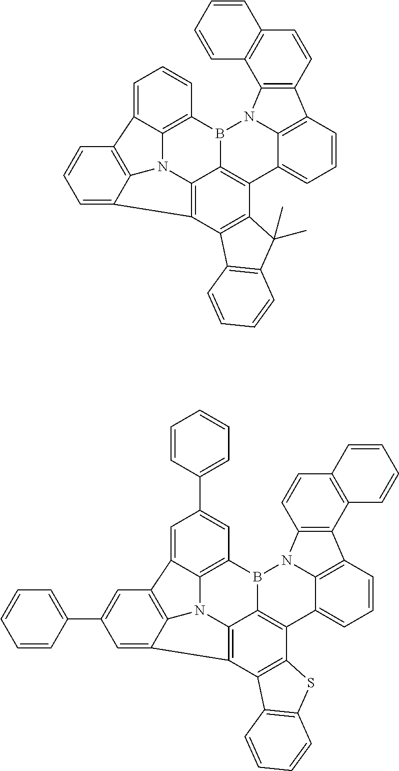 [SMILES: CC1(C)c2ccccc2-c2c1c1c3c4c2c2cccc5c6cccc(c6n4c52)B3n2c3c-1cccc3c1ccc3ccccc3c12 ; c1ccc(-c2cc3c4c(c2)c2cc(-c5ccccc5)cc5c6c7c(sc8ccccc87)c7c(c6n4c25)B3n2c3ccc4ccccc4c3c3cccc-7c32)cc1] 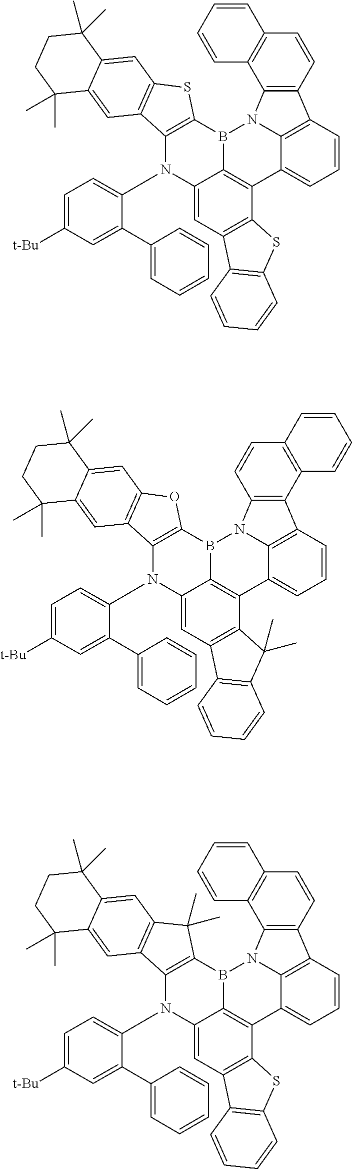 [SMILES: CC(C)(C)c1ccc(N2c3cc4c(sc5ccccc54)c4c3B(c3sc5cc6c(cc5c32)C(C)(C)CCC6(C)C)n2c3c-4cccc3c3ccc4ccccc4c32)c(-c2ccccc2)c1 ; CC(C)(C)c1ccc(N2c3cc4c(c5c3B(c3oc6cc7c(cc6c32)C(C)(C)CCC7(C)C)n2c3ccc6ccccc6c3c3cccc-5c32)C(C)(C)c2ccccc2-4)c(-c2ccccc2)c1 ; CC(C)(C)c1ccc(N2C3=C(B4c5c2cc2c(sc6ccccc62)c5-c2cccc5c6ccc7ccccc7c6n4c25)C(C)(C)c2cc4c(cc23)C(C)(C)CCC4(C)C)c(-c2ccccc2)c1] 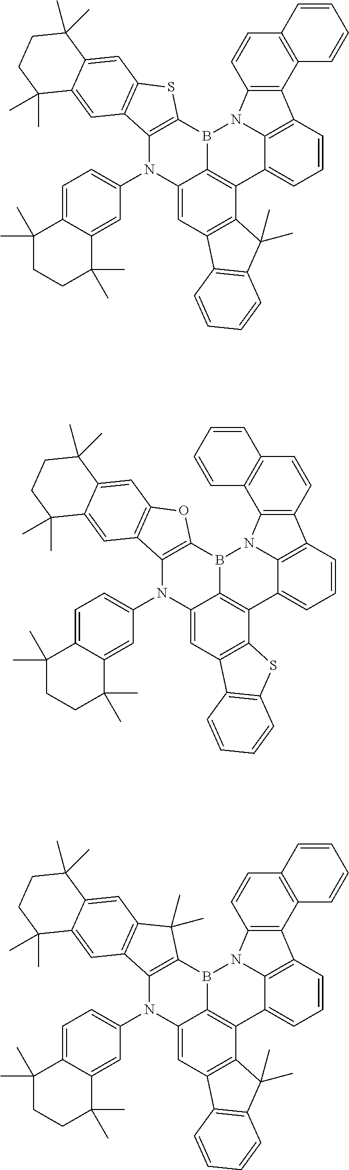 [SMILES: CC1(C)CCC(C)(C)c2cc(N3c4cc5c(c6c4B(c4sc7cc8c(cc7c43)C(C)(C)CCC8(C)C)n3c4ccc7ccccc7c4c4cccc-6c43)C(C)(C)c3ccccc3-5)ccc21 ; CC1(C)CCC(C)(C)c2cc(N3c4cc5c(sc6ccccc65)c5c4B(c4oc6cc7c(cc6c43)C(C)(C)CCC7(C)C)n3c4c-5cccc4c4ccc5ccccc5c43)ccc21 ; CC1(C)CCC(C)(C)c2cc(N3C4=C(B5c6c3cc3c(c6-c6cccc7c8c9ccccc9ccc8n5c67)C(C)(C)c5ccccc5-3)C(C)(C)c3cc5c(cc34)C(C)(C)CCC5(C)C)ccc21] 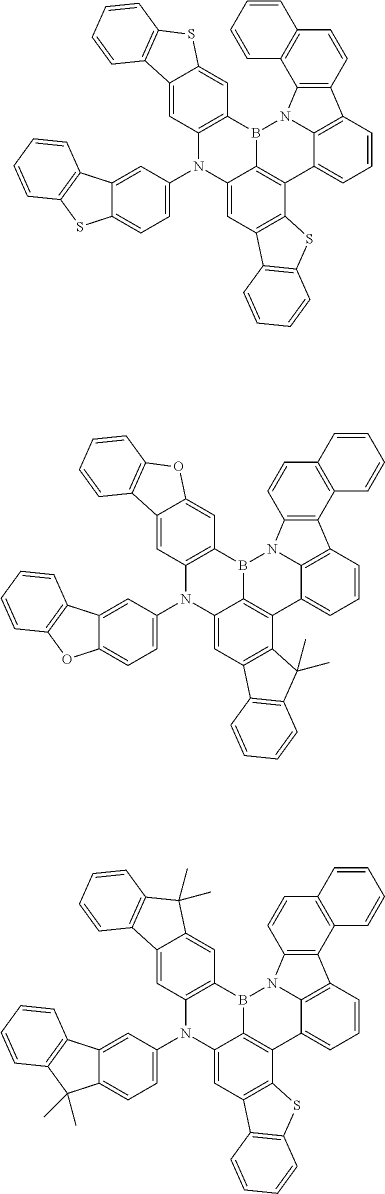 [SMILES: c1ccc2c(c1)ccc1c3cccc4c3n(c21)B1c2cc3sc5ccccc5c3cc2N(c2ccc3sc5ccccc5c3c2)c2cc3c(sc5ccccc53)c-4c21 ; CC1(C)c2ccccc2-c2cc3c4c(c21)-c1cccc2c5c6ccccc6ccc5n(c12)B4c1cc2oc4ccccc4c2cc1N3c1ccc2oc3ccccc3c2c1 ; CC1(C)c2ccccc2-c2cc(N3c4cc5c(cc4B4c6c3cc3c(sc7ccccc73)c6-c3cccc6c7c8ccccc8ccc7n4c36)C(C)(C)c3ccccc3-5)ccc21] 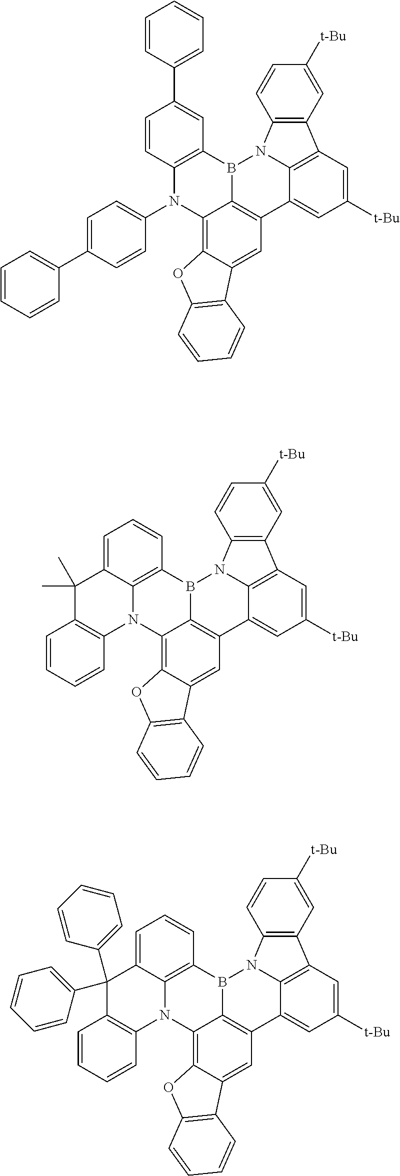 [SMILES: CC(C)(C)c1ccc2c(c1)c1cc(C(C)(C)C)cc3c1n2B1c2cc(-c4ccccc4)ccc2N(c2ccc(-c4ccccc4)cc2)c2c1c-3cc1c2oc2ccccc21 ; CC(C)(C)c1ccc2c(c1)c1cc(C(C)(C)C)cc3c1n2B1c2cccc4c2N(c2ccccc2C4(C)C)c2c1c-3cc1c2oc2ccccc21 ; CC(C)(C)c1ccc2c(c1)c1cc(C(C)(C)C)cc3c1n2B1c2cccc4c2N(c2ccccc2C4(c2ccccc2)c2ccccc2)c2c1c-3cc1c2oc2ccccc21] 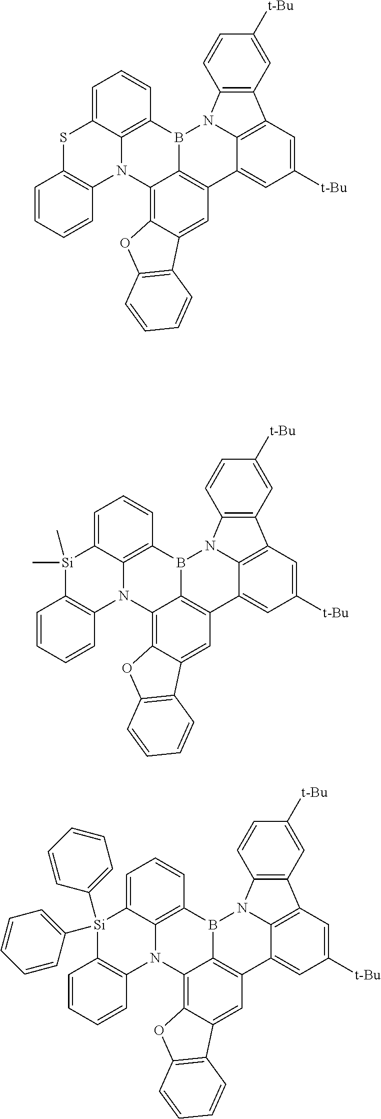 [SMILES: CC(C)(C)c1ccc2c(c1)c1cc(C(C)(C)C)cc3c1n2B1c2cccc4c2N(c2ccccc2S4)c2c1c-3cc1c2oc2ccccc21 ; CC(C)(C)c1ccc2c(c1)c1cc(C(C)(C)C)cc3c1n2B1c2cccc4c2N(c2ccccc2[Si]4(C)C)c2c1c-3cc1c2oc2ccccc21 ; CC(C)(C)c1ccc2c(c1)c1cc(C(C)(C)C)cc3c1n2B1c2cccc4c2N(c2ccccc2[Si]4(c2ccccc2)c2ccccc2)c2c1c-3cc1c2oc2ccccc21] 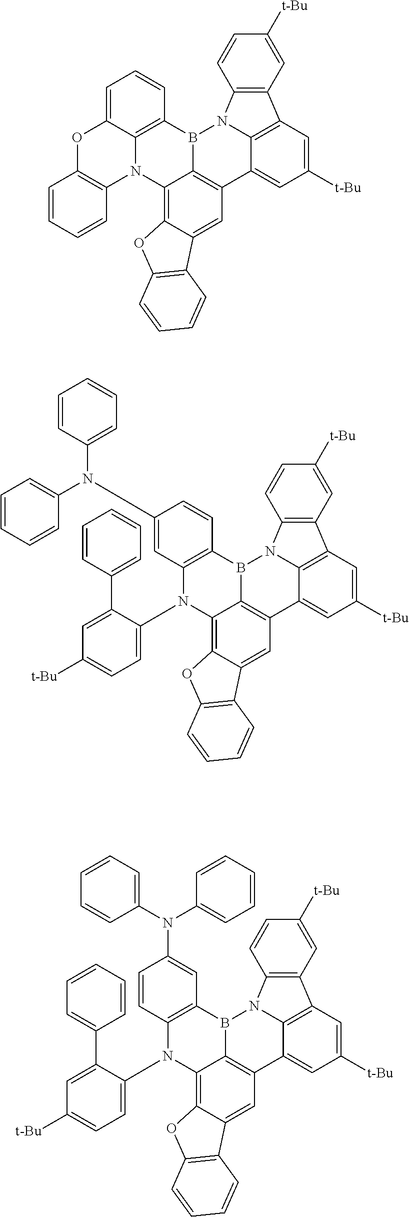 [SMILES: CC(C)(C)c1ccc2c(c1)c1cc(C(C)(C)C)cc3c1n2B1c2cccc4c2N(c2ccccc2O4)c2c1c-3cc1c2oc2ccccc21 ; CC(C)(C)c1ccc(N2c3cc(N(c4ccccc4)c4ccccc4)ccc3B3c4c(cc5c(oc6ccccc65)c42)-c2cc(C(C)(C)C)cc4c5cc(C(C)(C)C)ccc5n3c24)c(-c2ccccc2)c1 ; CC(C)(C)c1ccc(N2c3ccc(N(c4ccccc4)c4ccccc4)cc3B3c4c(cc5c(oc6ccccc65)c42)-c2cc(C(C)(C)C)cc4c5cc(C(C)(C)C)ccc5n3c24)c(-c2ccccc2)c1] 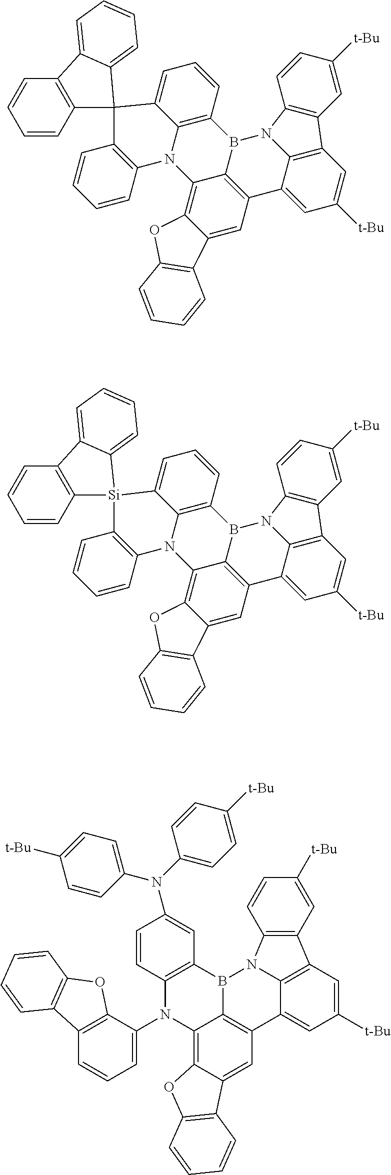 [SMILES: CC(C)(C)c1ccc2c(c1)c1cc(C(C)(C)C)cc3c1n2B1c2cccc4c2N(c2ccccc2C42c4ccccc4-c4ccccc42)c2c1c-3cc1c2oc2ccccc21 ; CC(C)(C)c1ccc2c(c1)c1cc(C(C)(C)C)cc3c1n2B1c2cccc4c2N(c2ccccc2[Si]42c4ccccc4-c4ccccc42)c2c1c-3cc1c2oc2ccccc21 ; CC(C)(C)c1ccc(N(c2ccc(C(C)(C)C)cc2)c2ccc3c(c2)B2c4c(cc5c(oc6ccccc65)c4N3c3cccc4c3oc3ccccc34)-c3cc(C(C)(C)C)cc4c5cc(C(C)(C)C)ccc5n2c34)cc1] 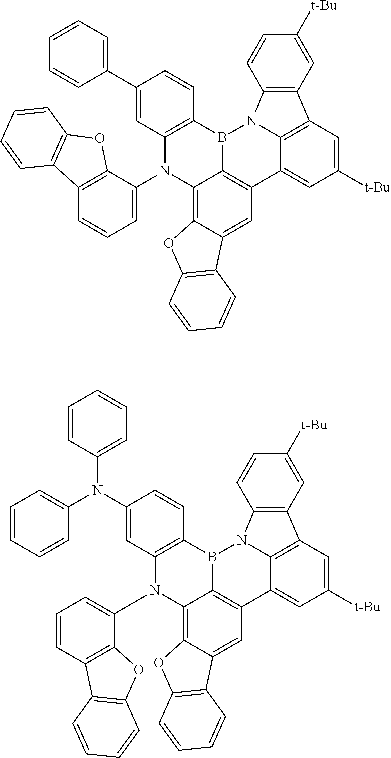 [SMILES: CC(C)(C)c1ccc2c(c1)c1cc(C(C)(C)C)cc3c1n2B1c2ccc(-c4ccccc4)cc2N(c2cccc4c2oc2ccccc24)c2c1c-3cc1c2oc2ccccc21 ; CC(C)(C)c1ccc2c(c1)c1cc(C(C)(C)C)cc3c1n2B1c2ccc(N(c4ccccc4)c4ccccc4)cc2N(c2cccc4c2oc2ccccc24)c2c1c-3cc1c2oc2ccccc21] 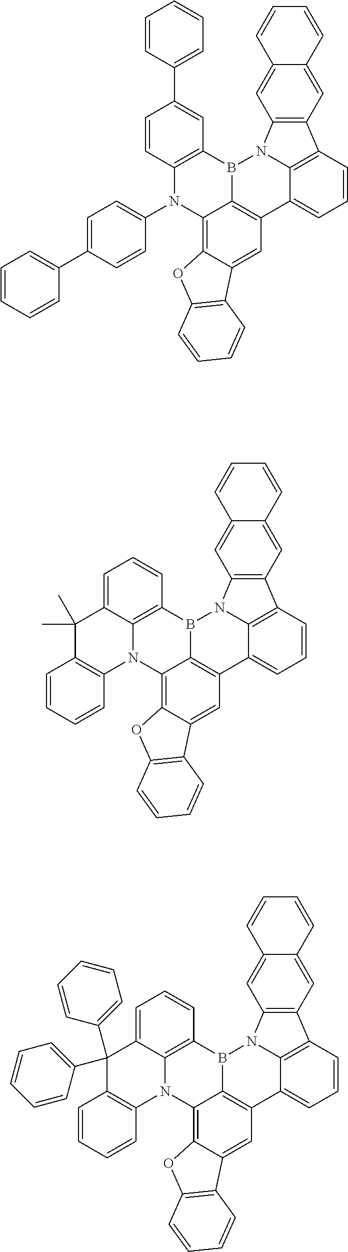 [SMILES: c1ccc(-c2ccc(N3c4ccc(-c5ccccc5)cc4B4c5c(cc6c(oc7ccccc76)c53)-c3cccc5c6cc7ccccc7cc6n4c35)cc2)cc1 ; CC1(C)c2ccccc2N2c3c(cccc31)B1c3c(cc4c(oc5ccccc54)c32)-c2cccc3c4cc5ccccc5cc4n1c23 ; c1ccc(C2(c3ccccc3)c3ccccc3N3c4c(cccc42)B2c4c(cc5c(oc6ccccc65)c43)-c3cccc4c5cc6ccccc6cc5n2c34)cc1] 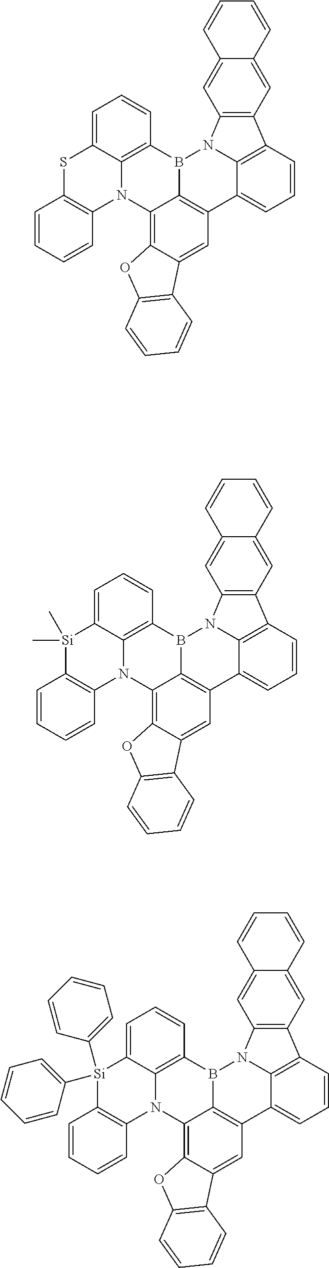 [SMILES: c1ccc2c(c1)Sc1cccc3c1N2c1c2c(cc4c1oc1ccccc14)-c1cccc4c5cc6ccccc6cc5n(c14)B32 ; C[Si]1(C)c2ccccc2N2c3c(cccc31)B1c3c(cc4c(oc5ccccc54)c32)-c2cccc3c4cc5ccccc5cc4n1c23 ; c1ccc([Si]2(c3ccccc3)c3ccccc3N3c4c(cccc42)B2c4c(cc5c(oc6ccccc65)c43)-c3cccc4c5cc6ccccc6cc5n2c34)cc1] 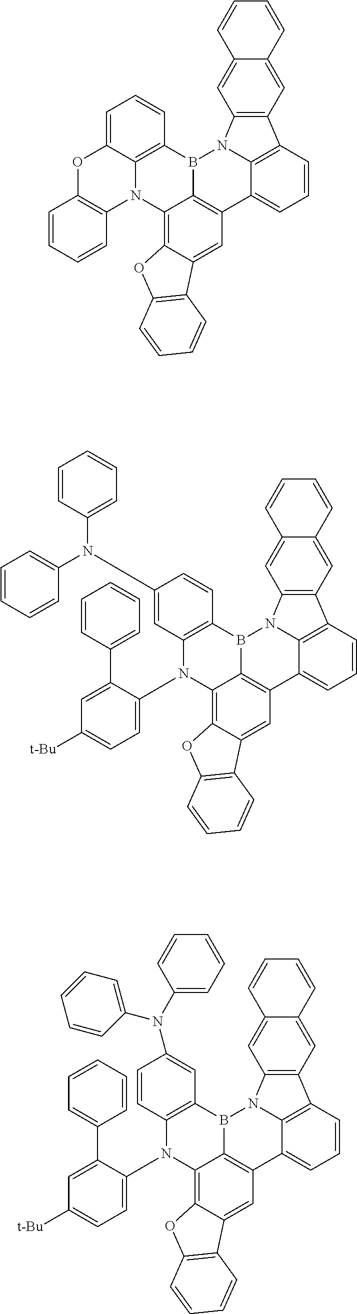 [SMILES: c1ccc2c(c1)Oc1cccc3c1N2c1c2c(cc4c1oc1ccccc14)-c1cccc4c5cc6ccccc6cc5n(c14)B32 ; CC(C)(C)c1ccc(N2c3cc(N(c4ccccc4)c4ccccc4)ccc3B3c4c(cc5c(oc6ccccc65)c42)-c2cccc4c5cc6ccccc6cc5n3c24)c(-c2ccccc2)c1 ; CC(C)(C)c1ccc(N2c3ccc(N(c4ccccc4)c4ccccc4)cc3B3c4c(cc5c(oc6ccccc65)c42)-c2cccc4c5cc6ccccc6cc5n3c24)c(-c2ccccc2)c1] 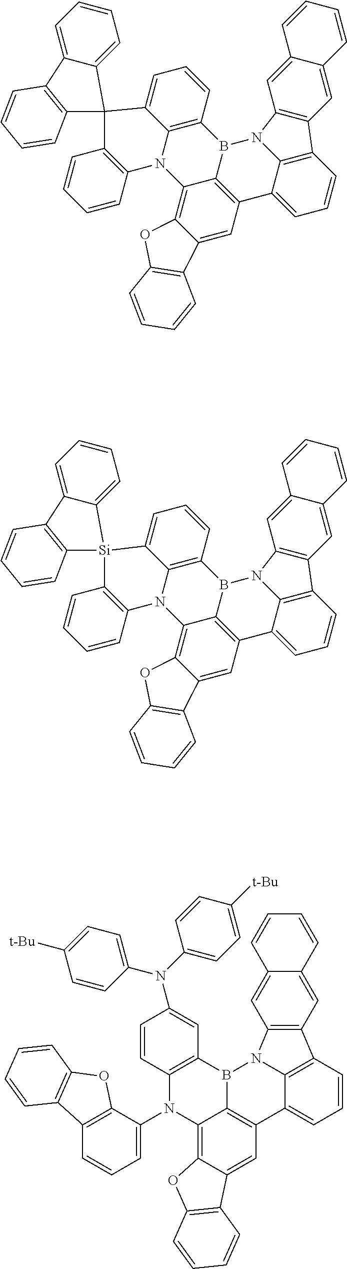 [SMILES: c1ccc2c(c1)-c1ccccc1C21c2ccccc2N2c3c(cccc31)B1c3c(cc4c(oc5ccccc54)c32)-c2cccc3c4cc5ccccc5cc4n1c23 ; c1ccc2c(c1)-c1ccccc1[Si]21c2ccccc2N2c3c(cccc31)B1c3c(cc4c(oc5ccccc54)c32)-c2cccc3c4cc5ccccc5cc4n1c23 ; CC(C)(C)c1ccc(N(c2ccc(C(C)(C)C)cc2)c2ccc3c(c2)B2c4c(cc5c(oc6ccccc65)c4N3c3cccc4c3oc3ccccc34)-c3cccc4c5cc6ccccc6cc5n2c34)cc1] 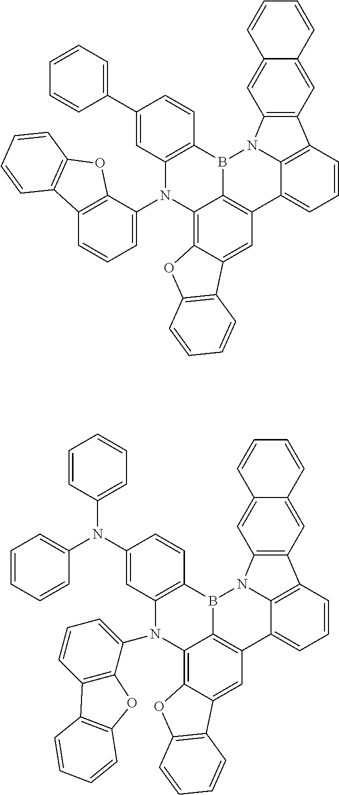 [SMILES: c1ccc(-c2ccc3c(c2)N(c2cccc4c2oc2ccccc24)c2c4c(cc5c2oc2ccccc25)-c2cccc5c6cc7ccccc7cc6n(c25)B34)cc1 ; c1ccc(N(c2ccccc2)c2ccc3c(c2)N(c2cccc4c2oc2ccccc24)c2c4c(cc5c2oc2ccccc25)-c2cccc5c6cc7ccccc7cc6n(c25)B34)cc1] 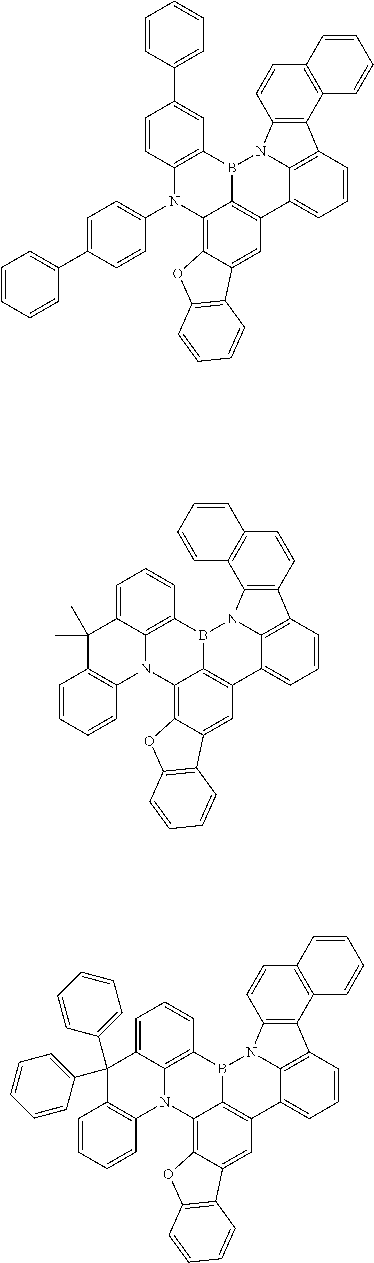 [SMILES: c1ccc(-c2ccc(N3c4ccc(-c5ccccc5)cc4B4c5c(cc6c(oc7ccccc76)c53)-c3cccc5c6c7ccccc7ccc6n4c35)cc2)cc1 ; CC1(C)c2ccccc2N2c3c(cccc31)B1c3c(cc4c(oc5ccccc54)c32)-c2cccc3c4ccc5ccccc5c4n1c23 ; c1ccc(C2(c3ccccc3)c3ccccc3N3c4c(cccc42)B2c4c(cc5c(oc6ccccc65)c43)-c3cccc4c5c6ccccc6ccc5n2c34)cc1] 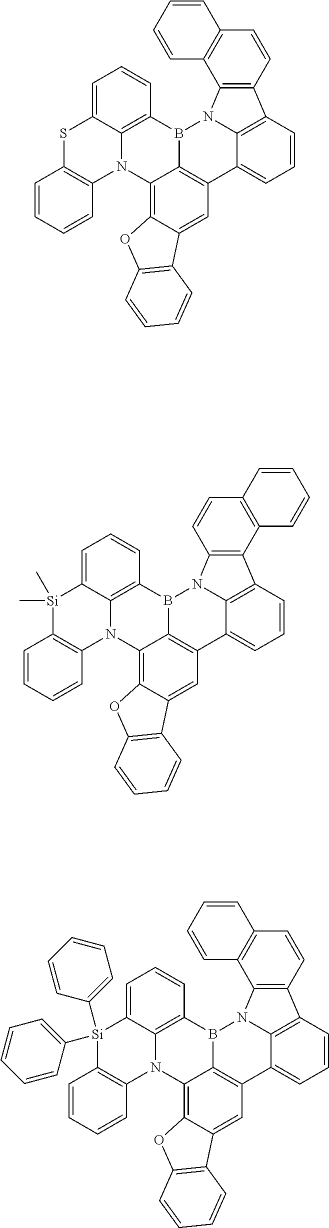 [SMILES: c1ccc2c(c1)Sc1cccc3c1N2c1c2c(cc4c1oc1ccccc14)-c1cccc4c5ccc6ccccc6c5n(c14)B32 ; C[Si]1(C)c2ccccc2N2c3c(cccc31)B1c3c(cc4c(oc5ccccc54)c32)-c2cccc3c4c5ccccc5ccc4n1c23 ; c1ccc([Si]2(c3ccccc3)c3ccccc3N3c4c(cccc42)B2c4c(cc5c(oc6ccccc65)c43)-c3cccc4c5ccc6ccccc6c5n2c34)cc1] 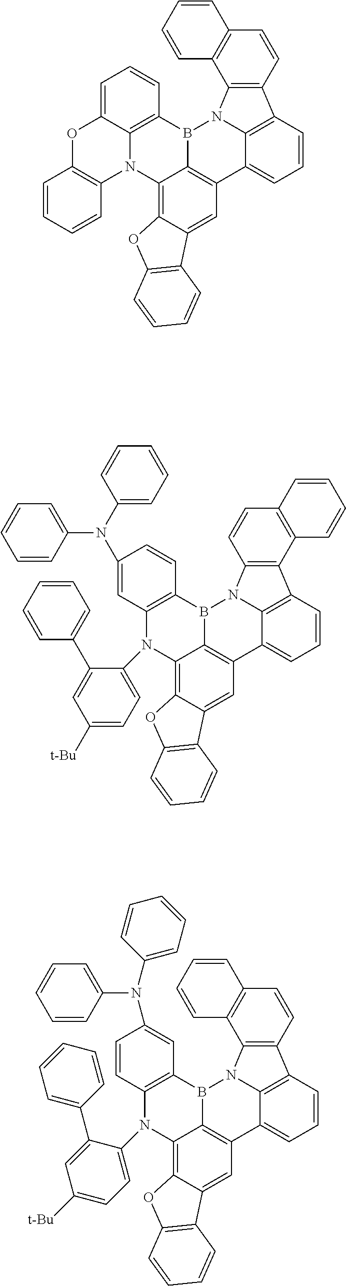 [SMILES: c1ccc2c(c1)Oc1cccc3c1N2c1c2c(cc4c1oc1ccccc14)-c1cccc4c5ccc6ccccc6c5n(c14)B32 ; CC(C)(C)c1ccc(N2c3cc(N(c4ccccc4)c4ccccc4)ccc3B3c4c(cc5c(oc6ccccc65)c42)-c2cccc4c5c6ccccc6ccc5n3c24)c(-c2ccccc2)c1 ; CC(C)(C)c1ccc(N2c3ccc(N(c4ccccc4)c4ccccc4)cc3B3c4c(cc5c(oc6ccccc65)c42)-c2cccc4c5ccc6ccccc6c5n3c24)c(-c2ccccc2)c1] 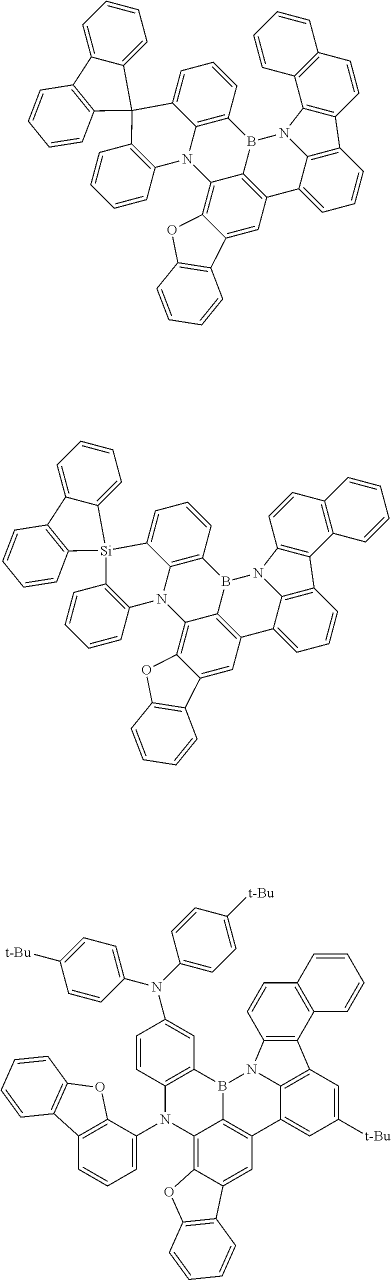 [SMILES: c1ccc2c(c1)-c1ccccc1C21c2ccccc2N2c3c(cccc31)B1c3c(cc4c(oc5ccccc54)c32)-c2cccc3c4ccc5ccccc5c4n1c23 ; c1ccc2c(c1)-c1ccccc1[Si]21c2ccccc2N2c3c(cccc31)B1c3c(cc4c(oc5ccccc54)c32)-c2cccc3c4c5ccccc5ccc4n1c23 ; CC(C)(C)c1ccc(N(c2ccc(C(C)(C)C)cc2)c2ccc3c(c2)B2c4c(cc5c(oc6ccccc65)c4N3c3cccc4c3oc3ccccc34)-c3cc(C(C)(C)C)cc4c5c6ccccc6ccc5n2c34)cc1] 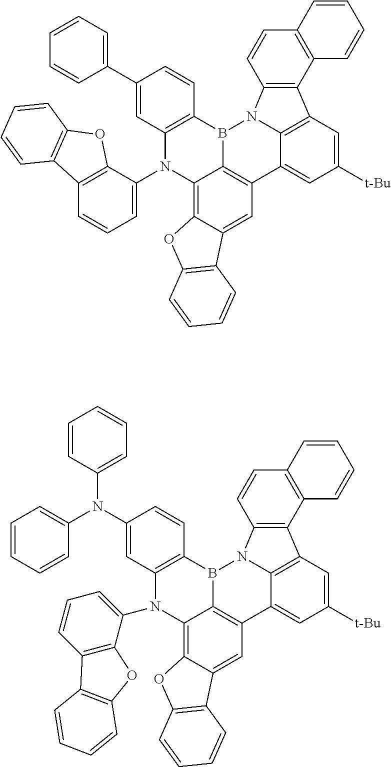 [SMILES: CC(C)(C)c1cc2c3c(c1)c1c4ccccc4ccc1n3B1c3ccc(-c4ccccc4)cc3N(c3cccc4c3oc3ccccc34)c3c1c-2cc1c3oc2ccccc21 ; CC(C)(C)c1cc2c3c(c1)c1c4ccccc4ccc1n3B1c3ccc(N(c4ccccc4)c4ccccc4)cc3N(c3cccc4c3oc3ccccc34)c3c1c-2cc1c3oc2ccccc21] 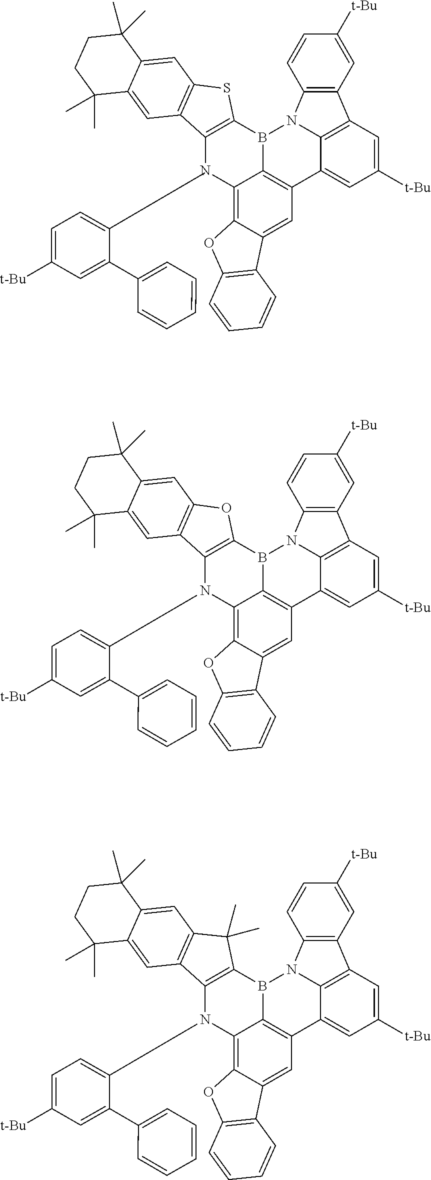 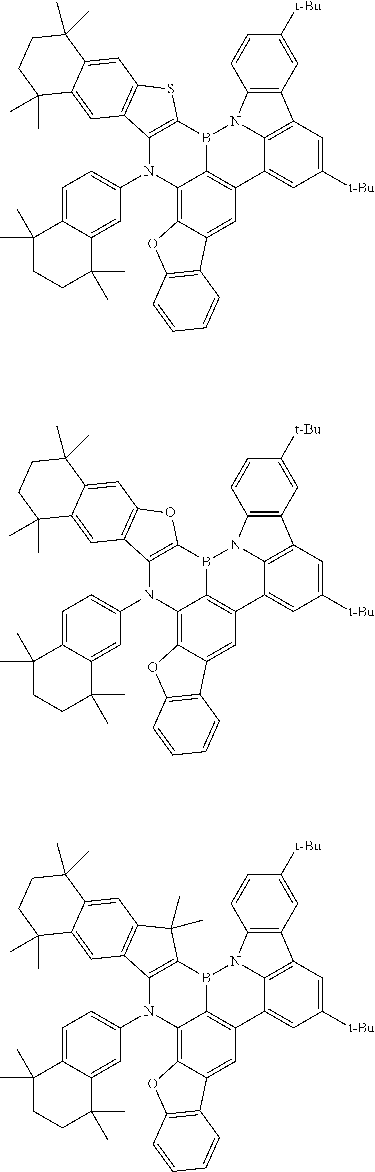 [SMILES: CC(C)(C)c1ccc2c(c1)c1cc(C(C)(C)C)cc3c1n2B1c2sc4cc5c(cc4c2N(c2ccc4c(c2)C(C)(C)CCC4(C)C)c2c1c-3cc1c2oc2ccccc21)C(C)(C)CCC5(C)C ; CC(C)(C)c1ccc2c(c1)c1cc(C(C)(C)C)cc3c1n2B1c2oc4cc5c(cc4c2N(c2ccc4c(c2)C(C)(C)CCC4(C)C)c2c1c-3cc1c2oc2ccccc21)C(C)(C)CCC5(C)C ; CC(C)(C)c1ccc2c(c1)c1cc(C(C)(C)C)cc3c1n2B1C2=C(c4cc5c(cc4C2(C)C)C(C)(C)CCC5(C)C)N(c2ccc4c(c2)C(C)(C)CCC4(C)C)c2c1c-3cc1c2oc2ccccc21] 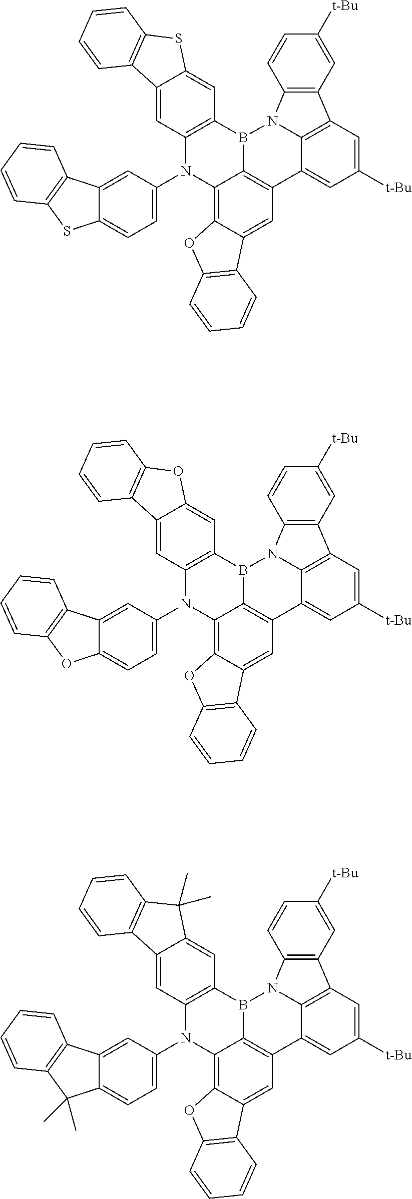 [SMILES: CC(C)(C)c1ccc2c(c1)c1cc(C(C)(C)C)cc3c1n2B1c2cc4sc5ccccc5c4cc2N(c2ccc4sc5ccccc5c4c2)c2c1c-3cc1c2oc2ccccc21 ; CC(C)(C)c1ccc2c(c1)c1cc(C(C)(C)C)cc3c1n2B1c2cc4oc5ccccc5c4cc2N(c2ccc4oc5ccccc5c4c2)c2c1c-3cc1c2oc2ccccc21 ; CC(C)(C)c1ccc2c(c1)c1cc(C(C)(C)C)cc3c1n2B1c2cc4c(cc2N(c2ccc5c(c2)-c2ccccc2C5(C)C)c2c1c-3cc1c2oc2ccccc21)-c1ccccc1C4(C)C] 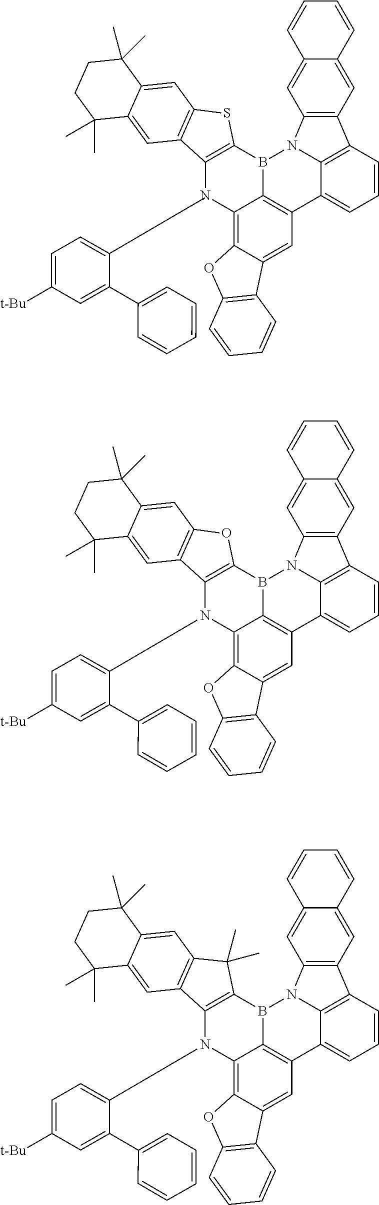 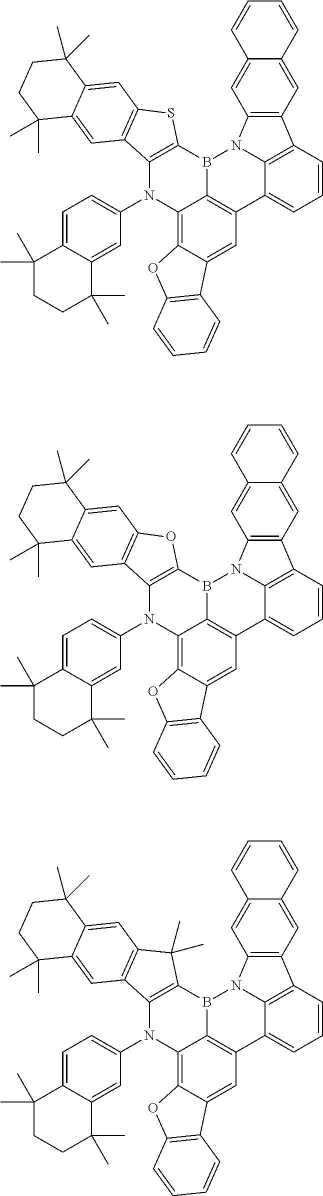 [SMILES: CC1(C)CCC(C)(C)c2cc(N3c4c(sc5cc6c(cc45)C(C)(C)CCC6(C)C)B4c5c(cc6c(oc7ccccc76)c53)-c3cccc5c6cc7ccccc7cc6n4c35)ccc21 ; CC1(C)CCC(C)(C)c2cc(N3c4c(oc5cc6c(cc45)C(C)(C)CCC6(C)C)B4c5c(cc6c(oc7ccccc76)c53)-c3cccc5c6cc7ccccc7cc6n4c35)ccc21 ; CC1(C)CCC(C)(C)c2cc(N3C4=C(B5c6c(cc7c(oc8ccccc87)c63)-c3cccc6c7cc8ccccc8cc7n5c36)C(C)(C)c3cc5c(cc34)C(C)(C)CCC5(C)C)ccc21] 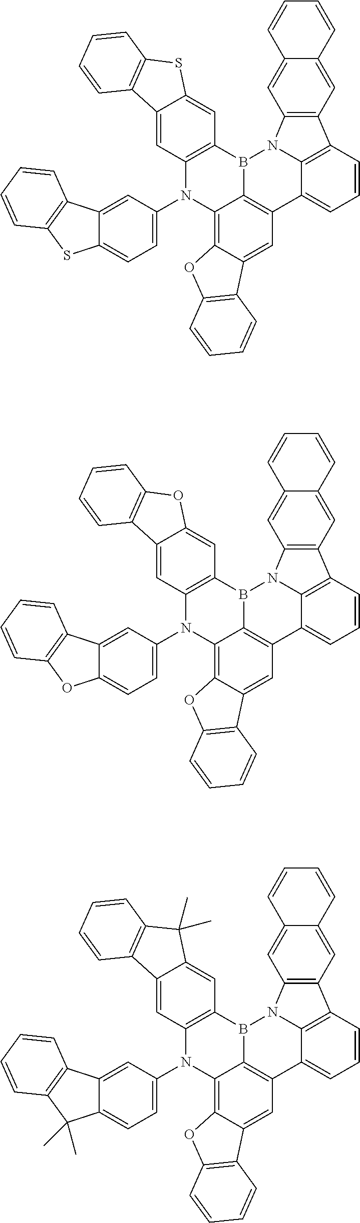 [SMILES: c1ccc2cc3c(cc2c1)c1cccc2c1n3B1c3cc4sc5ccccc5c4cc3N(c3ccc4sc5ccccc5c4c3)c3c1c-2cc1c3oc2ccccc21 ; c1ccc2cc3c(cc2c1)c1cccc2c1n3B1c3cc4oc5ccccc5c4cc3N(c3ccc4oc5ccccc5c4c3)c3c1c-2cc1c3oc2ccccc21 ; CC1(C)c2ccccc2-c2cc(N3c4cc5c(cc4B4c6c(cc7c(oc8ccccc87)c63)-c3cccc6c7cc8ccccc8cc7n4c36)C(C)(C)c3ccccc3-5)ccc21] 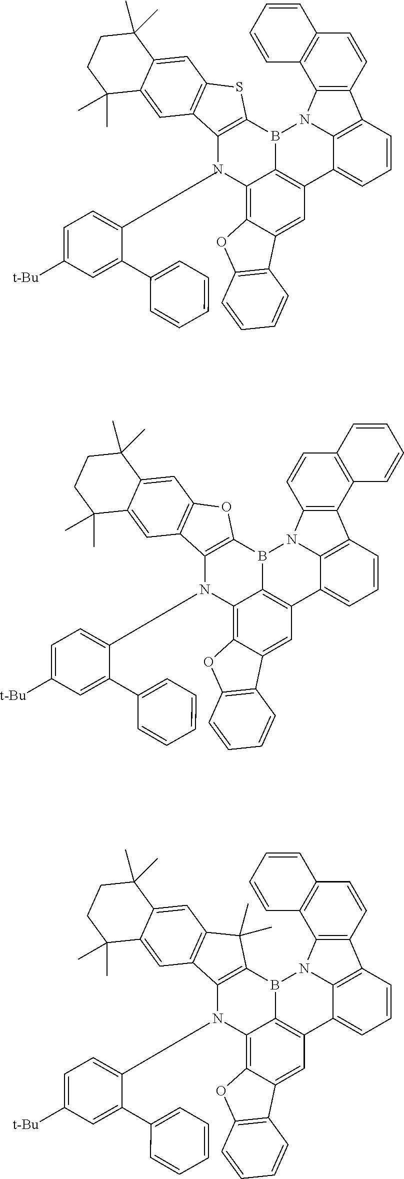 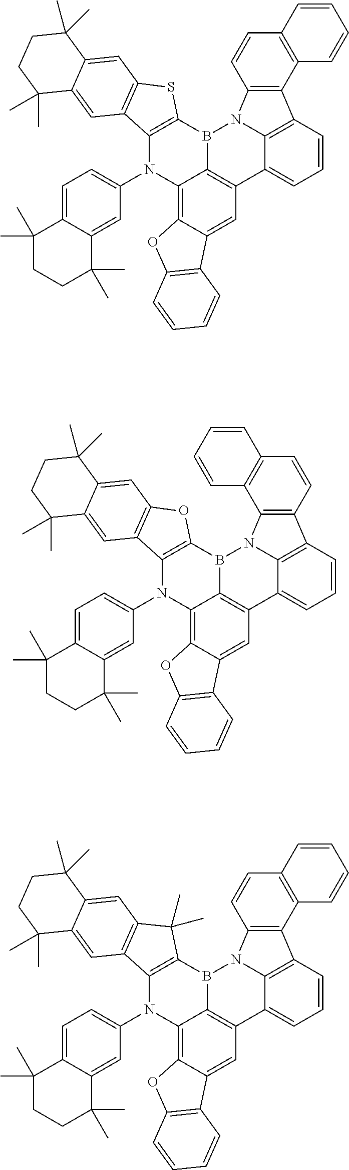 [SMILES: CC1(C)CCC(C)(C)c2cc(N3c4c(sc5cc6c(cc45)C(C)(C)CCC6(C)C)B4c5c(cc6c(oc7ccccc76)c53)-c3cccc5c6c7ccccc7ccc6n4c35)ccc21 ; CC1(C)CCC(C)(C)c2cc(N3c4c(oc5cc6c(cc45)C(C)(C)CCC6(C)C)B4c5c(cc6c(oc7ccccc76)c53)-c3cccc5c6ccc7ccccc7c6n4c35)ccc21 ; CC1(C)CCC(C)(C)c2cc(N3C4=C(B5c6c(cc7c(oc8ccccc87)c63)-c3cccc6c7c8ccccc8ccc7n5c36)C(C)(C)c3cc5c(cc34)C(C)(C)CCC5(C)C)ccc21] 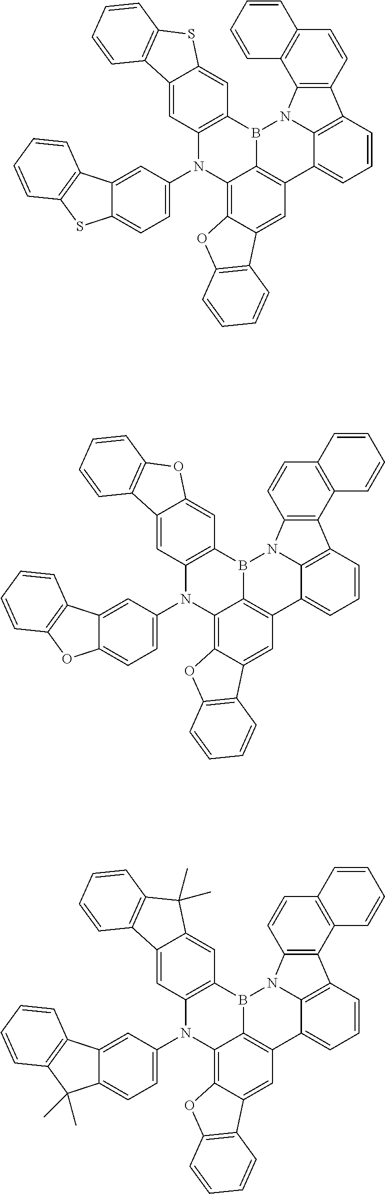 [SMILES: c1ccc2c(c1)ccc1c3cccc4c3n(c21)B1c2cc3sc5ccccc5c3cc2N(c2ccc3sc5ccccc5c3c2)c2c1c-4cc1c2oc2ccccc21 ; c1ccc2c(c1)ccc1c2c2cccc3c2n1B1c2cc4oc5ccccc5c4cc2N(c2ccc4oc5ccccc5c4c2)c2c1c-3cc1c2oc2ccccc21 ; CC1(C)c2ccccc2-c2cc(N3c4cc5c(cc4B4c6c(cc7c(oc8ccccc87)c63)-c3cccc6c7c8ccccc8ccc7n4c36)C(C)(C)c3ccccc3-5)ccc21] 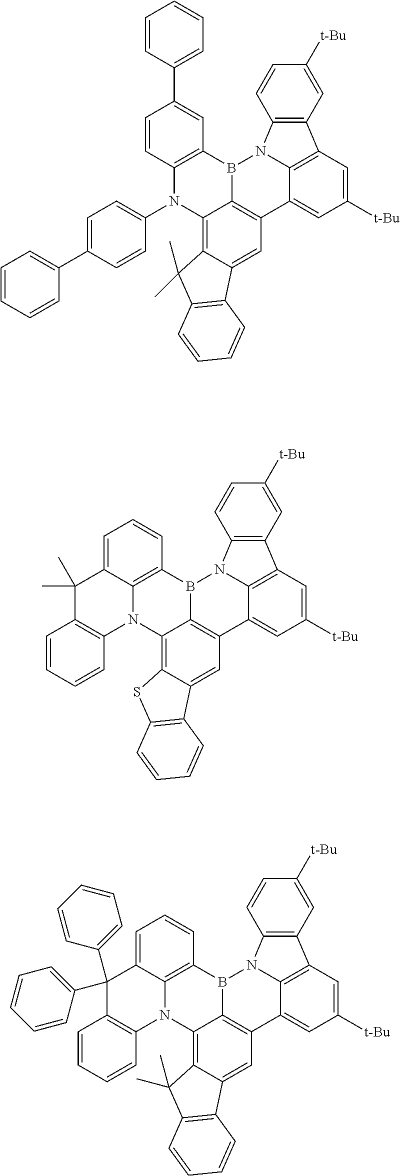 [SMILES: CC(C)(C)c1ccc2c(c1)c1cc(C(C)(C)C)cc3c1n2B1c2cc(-c4ccccc4)ccc2N(c2ccc(-c4ccccc4)cc2)c2c1c-3cc1c2C(C)(C)c2ccccc2-1 ; CC(C)(C)c1ccc2c(c1)c1cc(C(C)(C)C)cc3c1n2B1c2cccc4c2N(c2ccccc2C4(C)C)c2c1c-3cc1c2sc2ccccc21 ; CC(C)(C)c1ccc2c(c1)c1cc(C(C)(C)C)cc3c1n2B1c2cccc4c2N(c2ccccc2C4(c2ccccc2)c2ccccc2)c2c1c-3cc1c2C(C)(C)c2ccccc2-1] 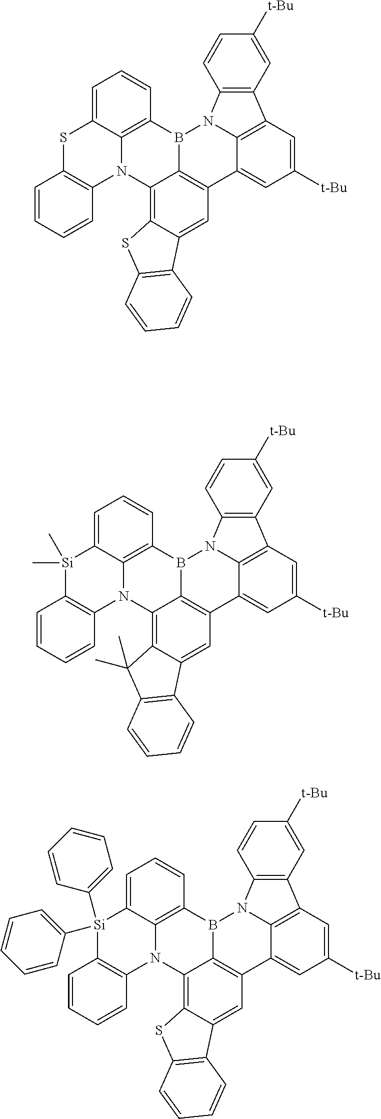 [SMILES: CC(C)(C)c1ccc2c(c1)c1cc(C(C)(C)C)cc3c1n2B1c2cccc4c2N(c2ccccc2S4)c2c1c-3cc1c2sc2ccccc21 ; CC(C)(C)c1ccc2c(c1)c1cc(C(C)(C)C)cc3c1n2B1c2cccc4c2N(c2ccccc2[Si]4(C)C)c2c1c-3cc1c2C(C)(C)c2ccccc2-1 ; CC(C)(C)c1ccc2c(c1)c1cc(C(C)(C)C)cc3c1n2B1c2cccc4c2N(c2ccccc2[Si]4(c2ccccc2)c2ccccc2)c2c1c-3cc1c2sc2ccccc21] 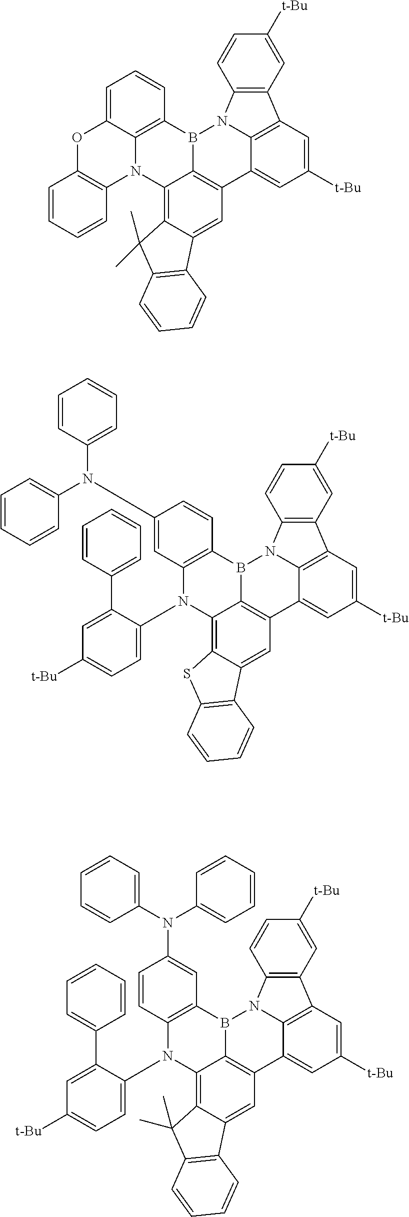 [SMILES: CC(C)(C)c1ccc2c(c1)c1cc(C(C)(C)C)cc3c1n2B1c2cccc4c2N(c2ccccc2O4)c2c1c-3cc1c2C(C)(C)c2ccccc2-1 ; CC(C)(C)c1ccc(N2c3cc(N(c4ccccc4)c4ccccc4)ccc3B3c4c(cc5c(sc6ccccc65)c42)-c2cc(C(C)(C)C)cc4c5cc(C(C)(C)C)ccc5n3c24)c(-c2ccccc2)c1 ; CC(C)(C)c1ccc(N2c3ccc(N(c4ccccc4)c4ccccc4)cc3B3c4c(cc5c(c42)C(C)(C)c2ccccc2-5)-c2cc(C(C)(C)C)cc4c5cc(C(C)(C)C)ccc5n3c24)c(-c2ccccc2)c1] 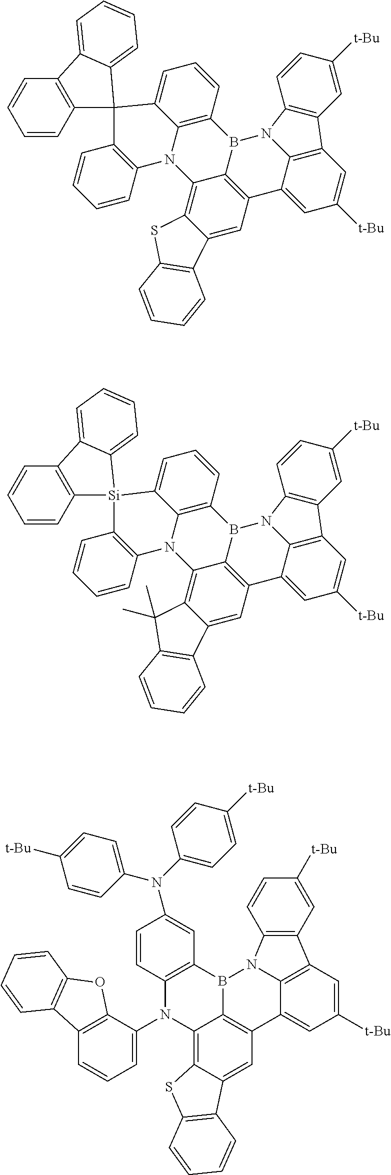 [SMILES: CC(C)(C)c1ccc2c(c1)c1cc(C(C)(C)C)cc3c1n2B1c2cccc4c2N(c2ccccc2C42c4ccccc4-c4ccccc42)c2c1c-3cc1c2sc2ccccc21 ; CC(C)(C)c1ccc2c(c1)c1cc(C(C)(C)C)cc3c1n2B1c2cccc4c2N(c2ccccc2[Si]42c4ccccc4-c4ccccc42)c2c1c-3cc1c2C(C)(C)c2ccccc2-1 ; CC(C)(C)c1ccc(N(c2ccc(C(C)(C)C)cc2)c2ccc3c(c2)B2c4c(cc5c(sc6ccccc65)c4N3c3cccc4c3oc3ccccc34)-c3cc(C(C)(C)C)cc4c5cc(C(C)(C)C)ccc5n2c34)cc1] 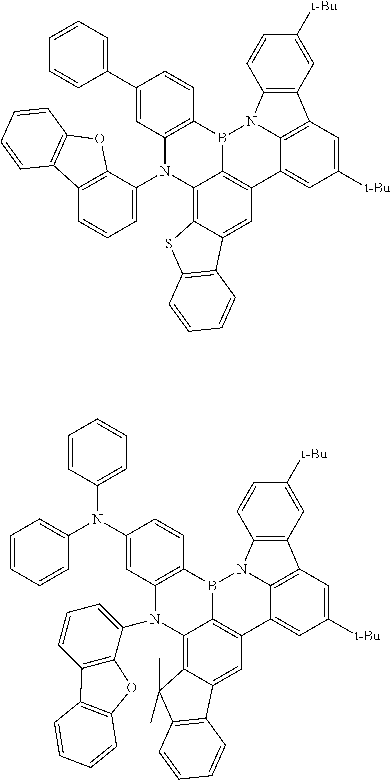 [SMILES: CC(C)(C)c1ccc2c(c1)c1cc(C(C)(C)C)cc3c1n2B1c2ccc(-c4ccccc4)cc2N(c2cccc4c2oc2ccccc24)c2c1c-3cc1c2sc2ccccc21 ; CC(C)(C)c1ccc2c(c1)c1cc(C(C)(C)C)cc3c1n2B1c2ccc(N(c4ccccc4)c4ccccc4)cc2N(c2cccc4c2oc2ccccc24)c2c1c-3cc1c2C(C)(C)c2ccccc2-1] 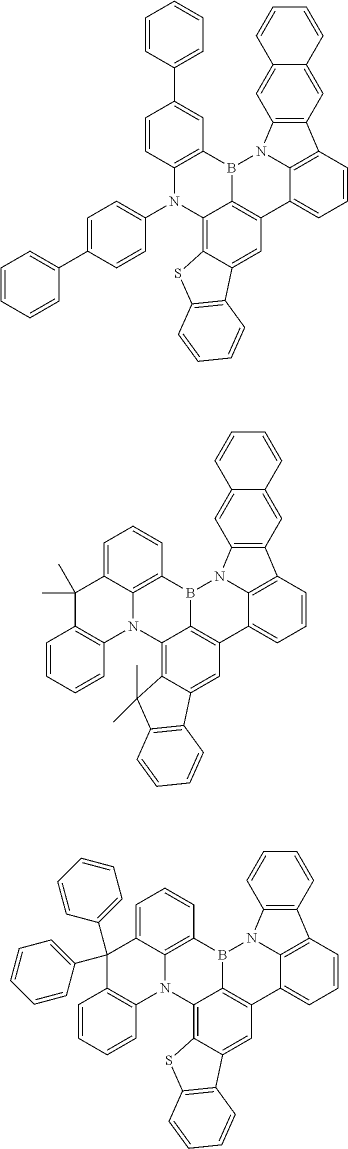 [SMILES: c1ccc(-c2ccc(N3c4ccc(-c5ccccc5)cc4B4c5c(cc6c(sc7ccccc76)c53)-c3cccc5c6cc7ccccc7cc6n4c35)cc2)cc1 ; CC1(C)c2ccccc2N2c3c(cccc31)B1c3c(cc4c(c32)C(C)(C)c2ccccc2-4)-c2cccc3c4cc5ccccc5cc4n1c23 ; c1ccc(C2(c3ccccc3)c3ccccc3N3c4c(cccc42)B2c4c(cc5c(sc6ccccc65)c43)-c3cccc4c5ccccc5n2c34)cc1] 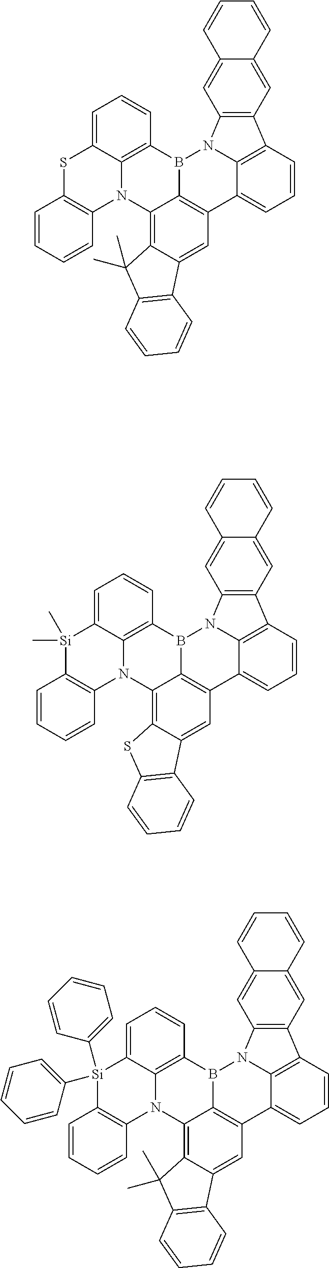 [SMILES: CC1(C)c2ccccc2-c2cc3c4c(c21)N1c2ccccc2Sc2cccc(c21)B4n1c2cc4ccccc4cc2c2cccc-3c21 ; C[Si]1(C)c2ccccc2N2c3c(cccc31)B1c3c(cc4c(sc5ccccc54)c32)-c2cccc3c4cc5ccccc5cc4n1c23 ; CC1(C)c2ccccc2-c2cc3c4c(c21)N1c2ccccc2[Si](c2ccccc2)(c2ccccc2)c2cccc(c21)B4n1c2cc4ccccc4cc2c2cccc-3c21] 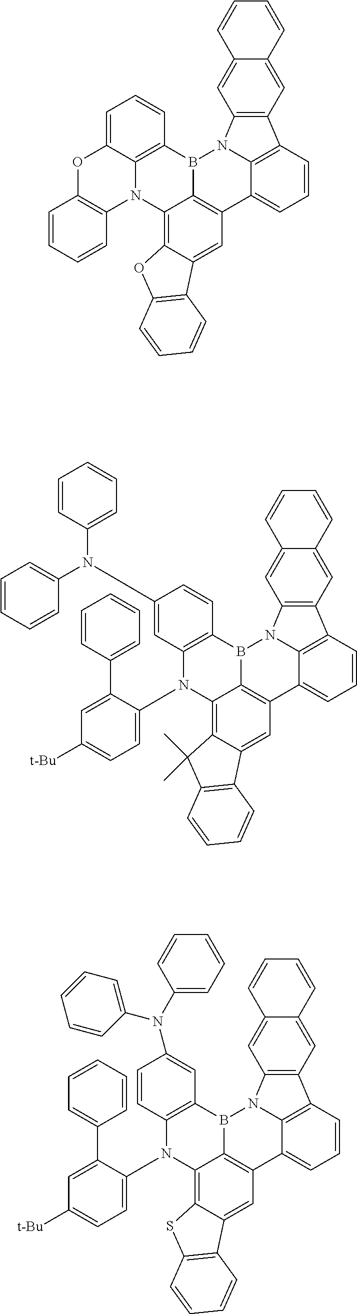 [SMILES: c1ccc2c(c1)Oc1cccc3c1N2c1c2c(cc4c1oc1ccccc14)-c1cccc4c5cc6ccccc6cc5n(c14)B32 ; CC(C)(C)c1ccc(N2c3cc(N(c4ccccc4)c4ccccc4)ccc3B3c4c(cc5c(c42)C(C)(C)c2ccccc2-5)-c2cccc4c5cc6ccccc6cc5n3c24)c(-c2ccccc2)c1 ; CC(C)(C)c1ccc(N2c3ccc(N(c4ccccc4)c4ccccc4)cc3B3c4c(cc5c(sc6ccccc65)c42)-c2cccc4c5cc6ccccc6cc5n3c24)c(-c2ccccc2)c1] 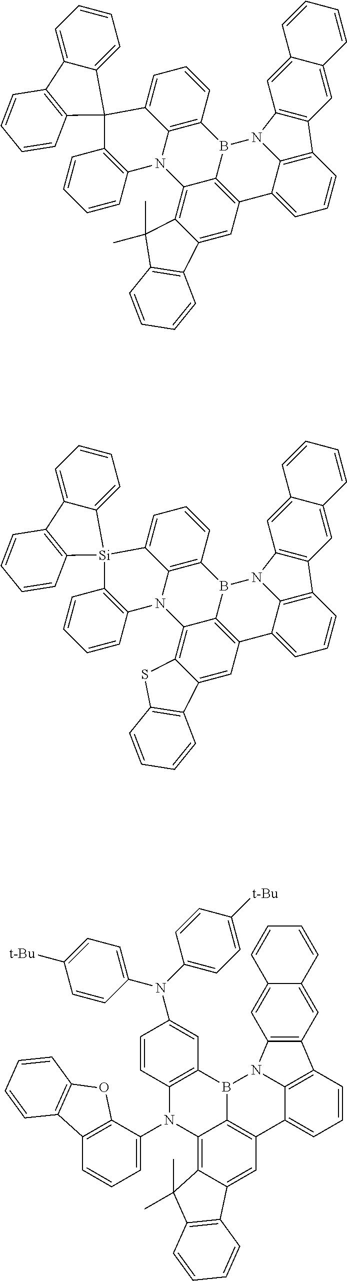 [SMILES: CC1(C)c2ccccc2-c2cc3c4c(c21)N1c2ccccc2C2(c5ccccc5-c5ccccc52)c2cccc(c21)B4n1c2cc4ccccc4cc2c2cccc-3c21 ; c1ccc2c(c1)-c1ccccc1[Si]21c2ccccc2N2c3c(cccc31)B1c3c(cc4c(sc5ccccc54)c32)-c2cccc3c4cc5ccccc5cc4n1c23 ; CC(C)(C)c1ccc(N(c2ccc(C(C)(C)C)cc2)c2ccc3c(c2)B2c4c(cc5c(c4N3c3cccc4c3oc3ccccc34)C(C)(C)c3ccccc3-5)-c3cccc4c5cc6ccccc6cc5n2c34)cc1] 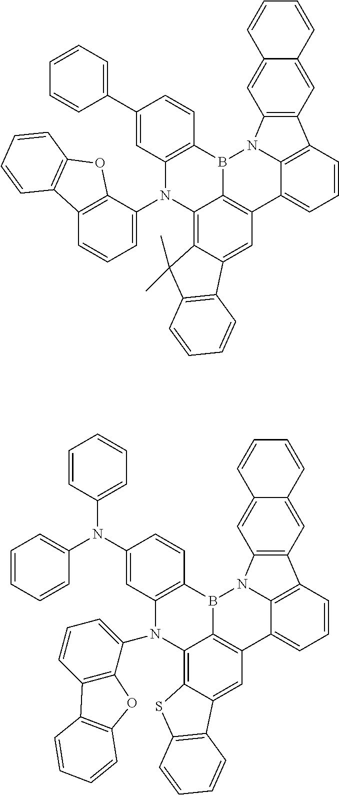 [SMILES: CC1(C)c2ccccc2-c2cc3c4c(c21)N(c1cccc2c1oc1ccccc12)c1cc(-c2ccccc2)ccc1B4n1c2cc4ccccc4cc2c2cccc-3c21 ; c1ccc(N(c2ccccc2)c2ccc3c(c2)N(c2cccc4c2oc2ccccc24)c2c4c(cc5c2sc2ccccc25)-c2cccc5c6cc7ccccc7cc6n(c25)B34)cc1] 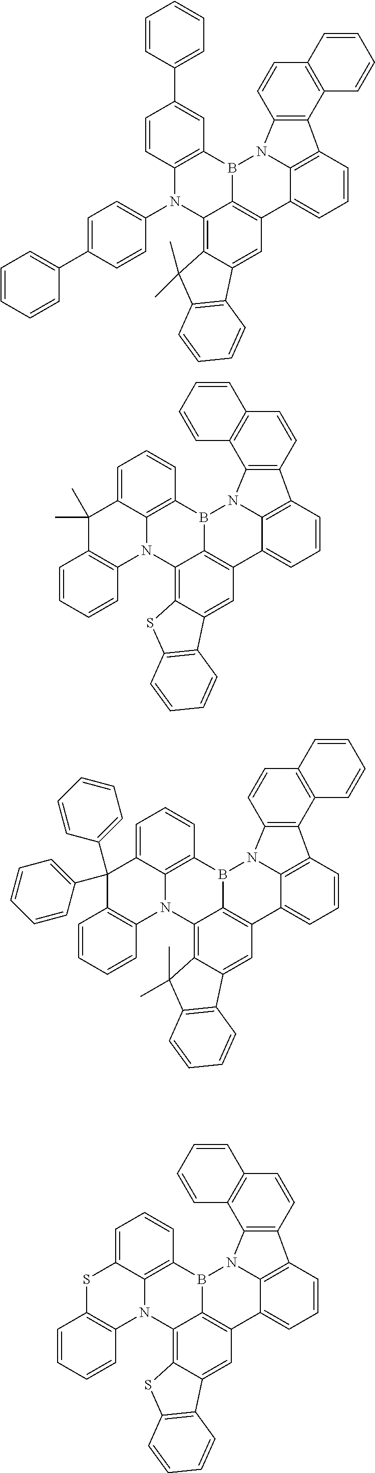 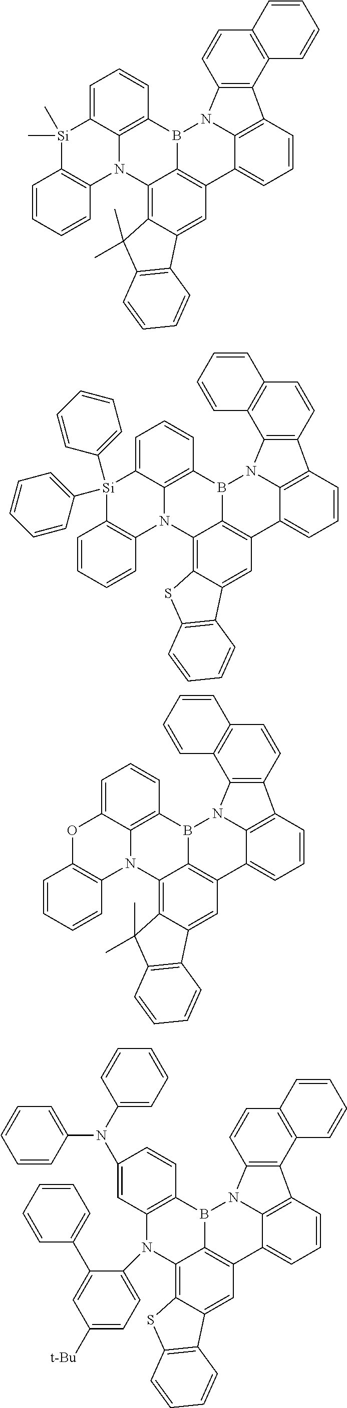 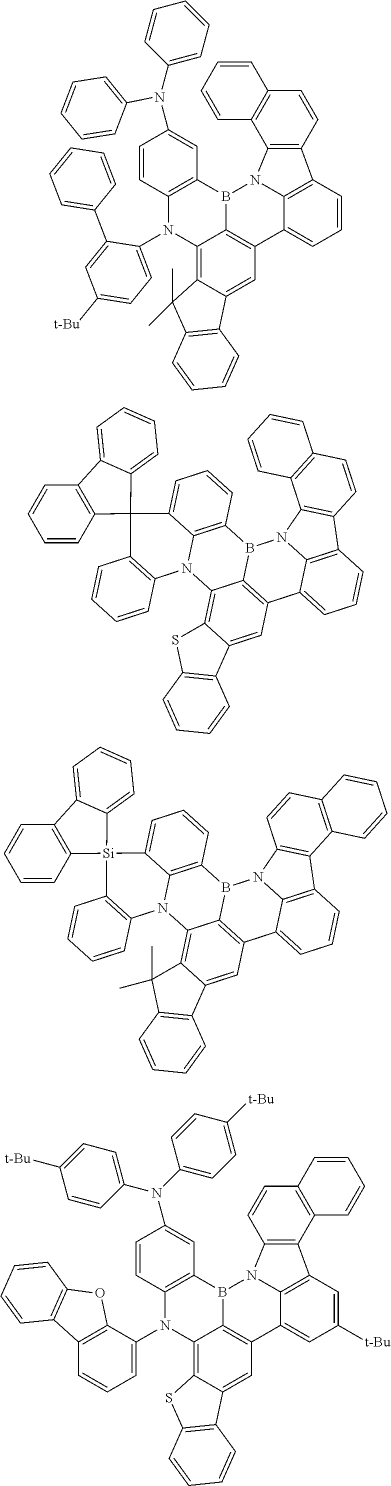 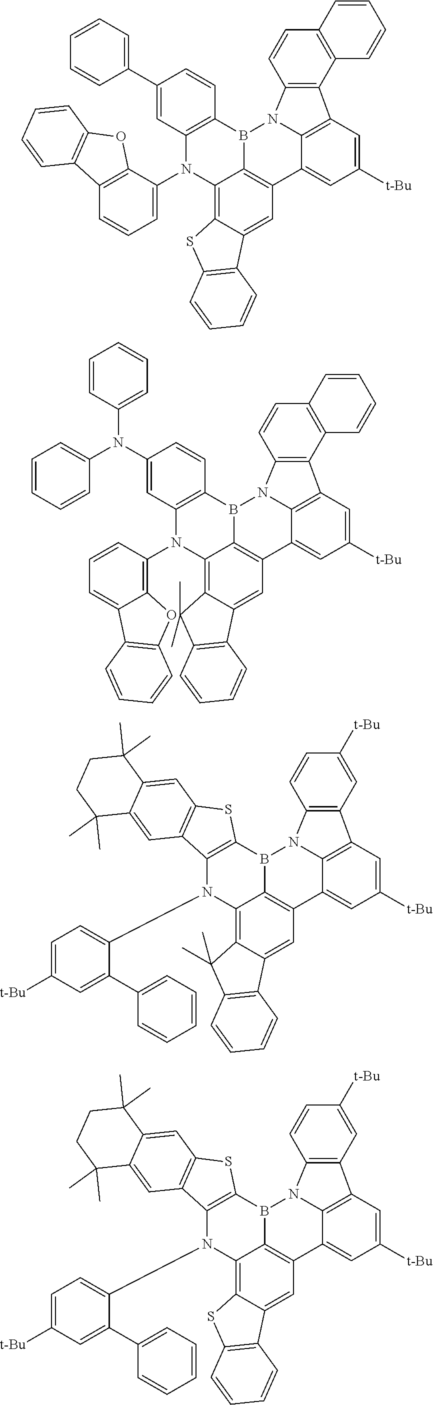 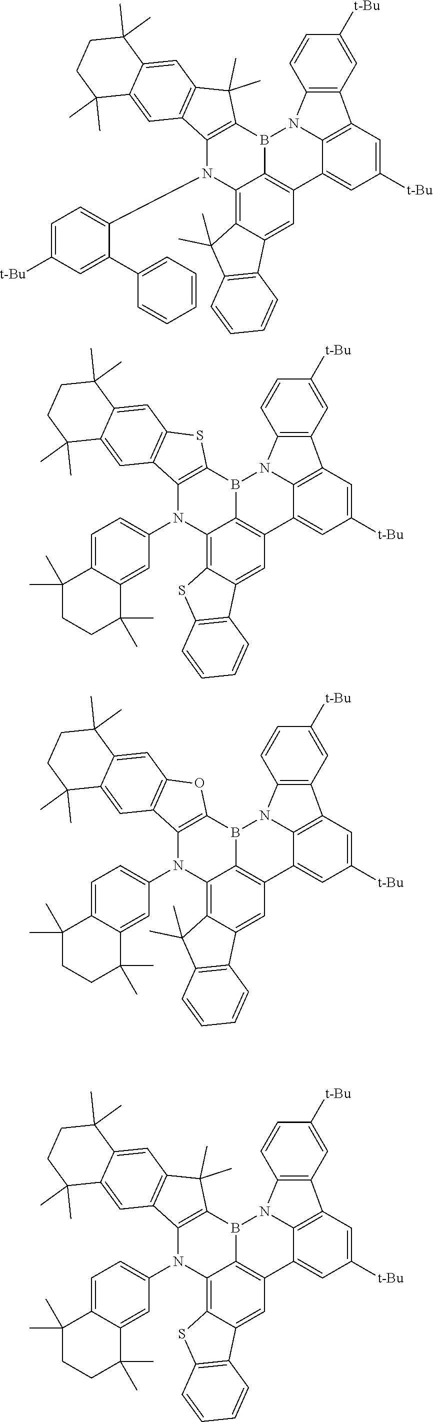 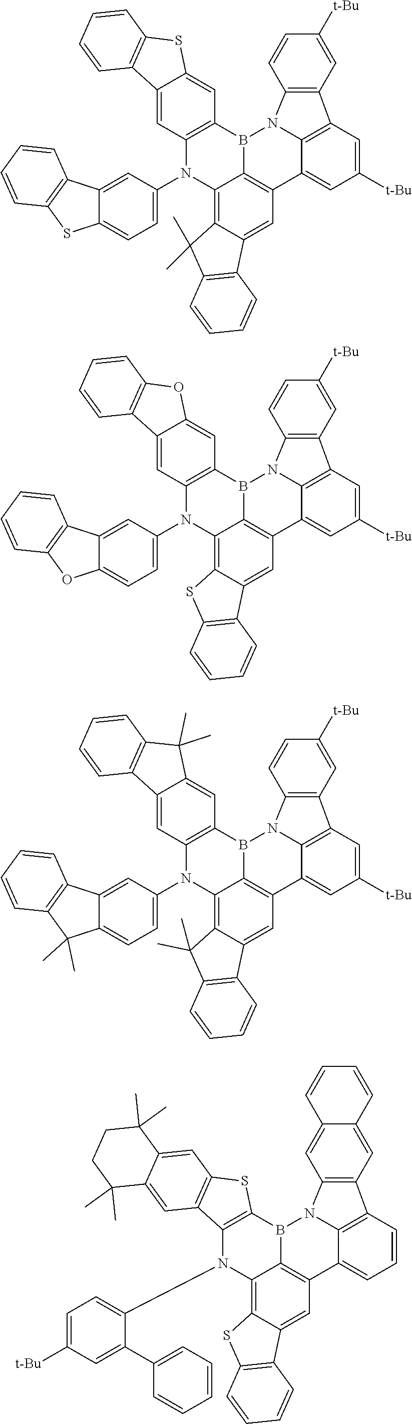 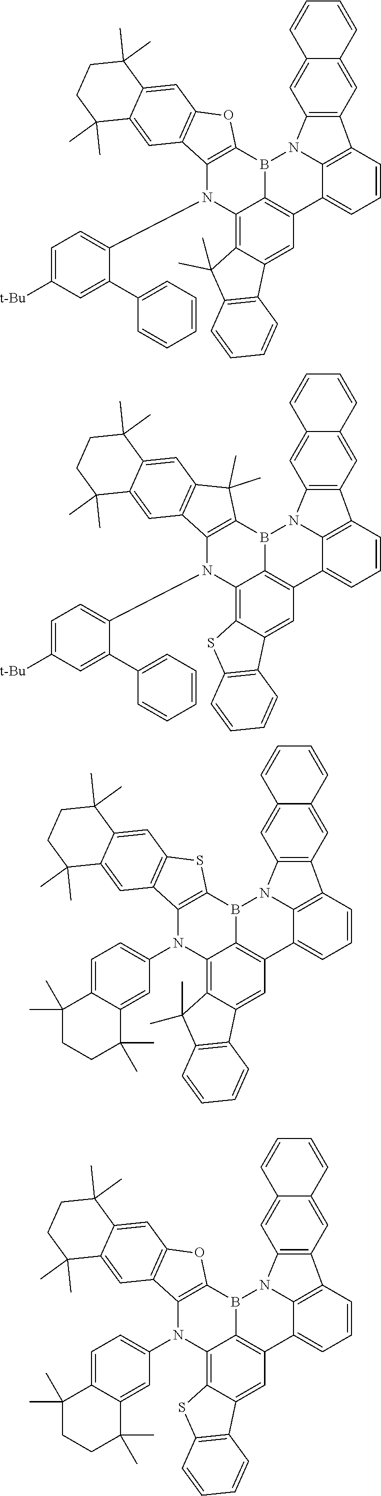 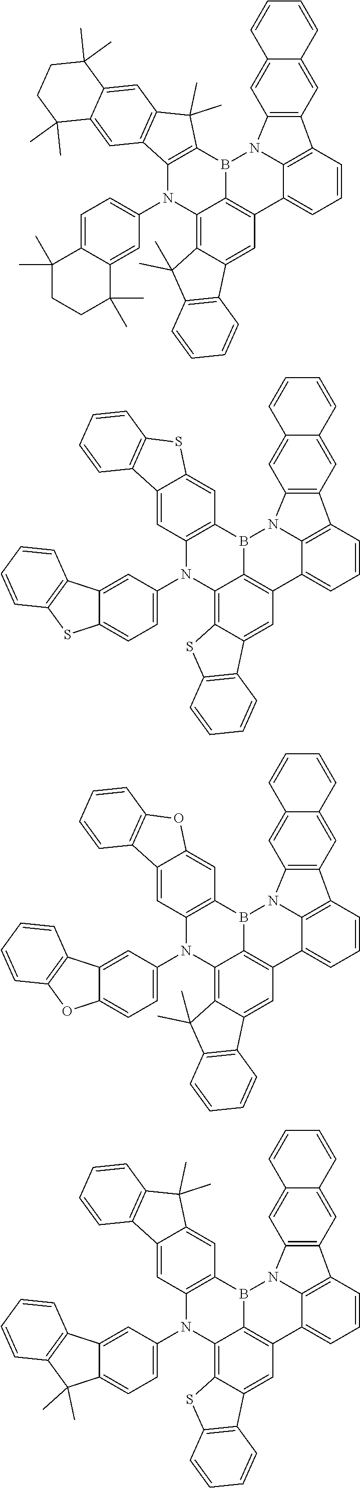 [SMILES: CC1(C)CCC(C)(C)c2cc(N3C4=C(B5c6c(cc7c(c63)C(C)(C)c3ccccc3-7)-c3cccc6c7cc8ccccc8cc7n5c36)C(C)(C)c3cc5c(cc34)C(C)(C)CCC5(C)C)ccc21 ; c1ccc2cc3c(cc2c1)c1cccc2c1n3B1c3cc4sc5ccccc5c4cc3N(c3ccc4sc5ccccc5c4c3)c3c1c-2cc1c3sc2ccccc21 ; CC1(C)c2ccccc2-c2cc3c4c(c21)N(c1ccc2oc5ccccc5c2c1)c1cc2c(cc1B4n1c4cc5ccccc5cc4c4cccc-3c41)oc1ccccc12 ; CC1(C)c2ccccc2-c2cc(N3c4cc5c(cc4B4c6c(cc7c(sc8ccccc87)c63)-c3cccc6c7cc8ccccc8cc7n4c36)C(C)(C)c3ccccc3-5)ccc21] 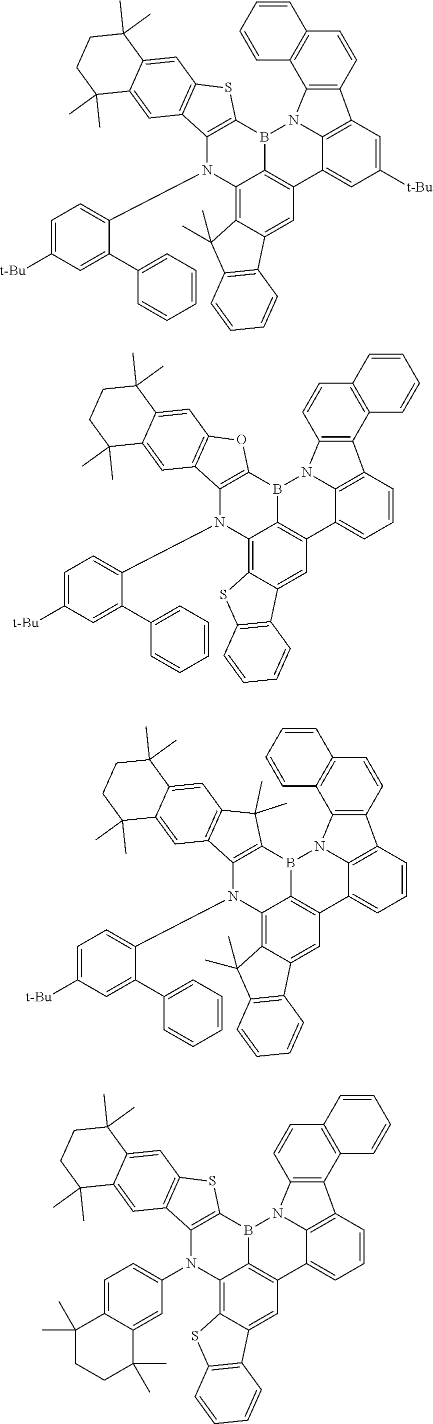 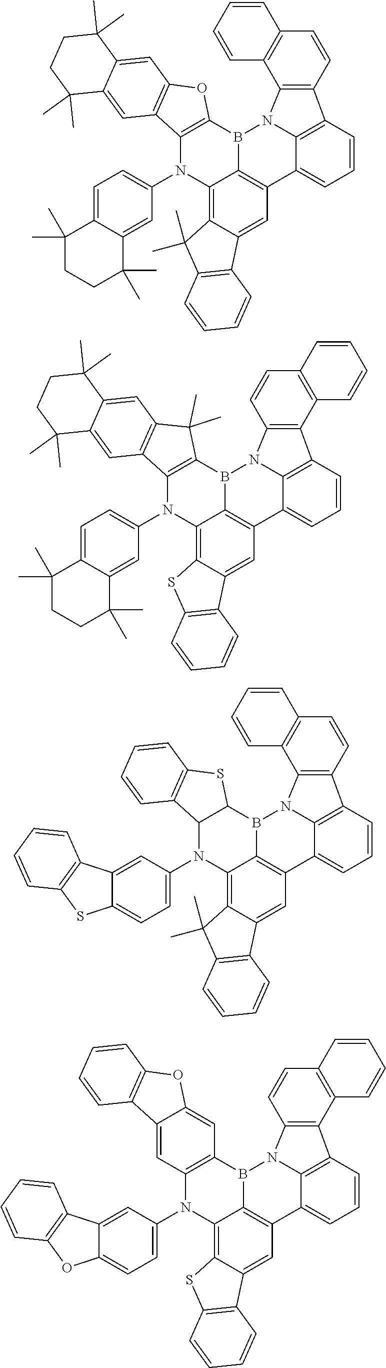 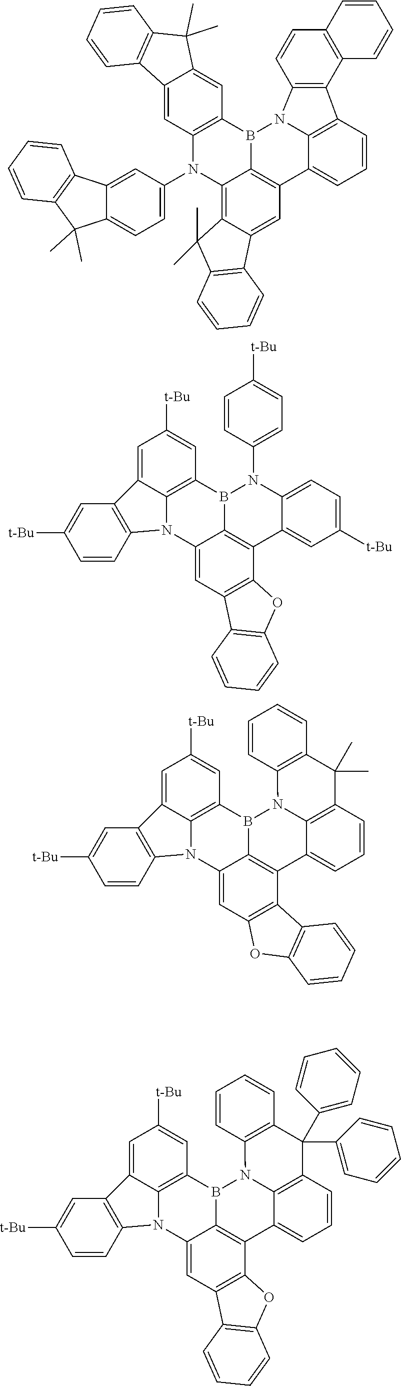 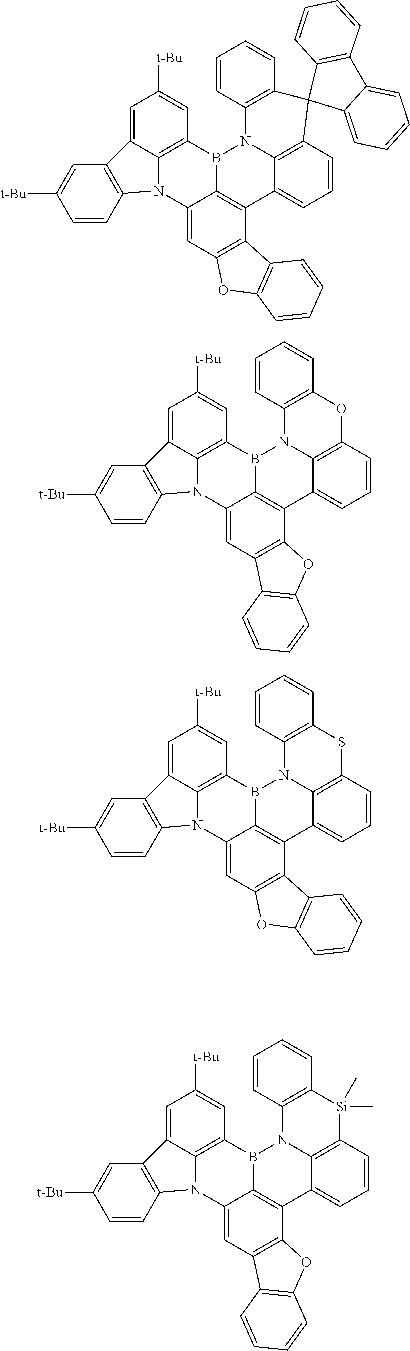 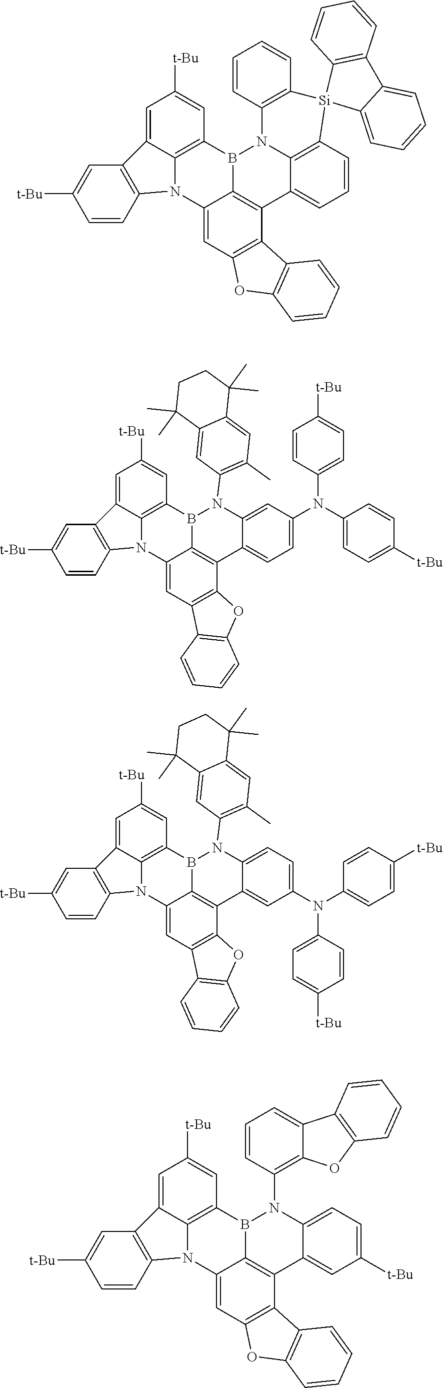 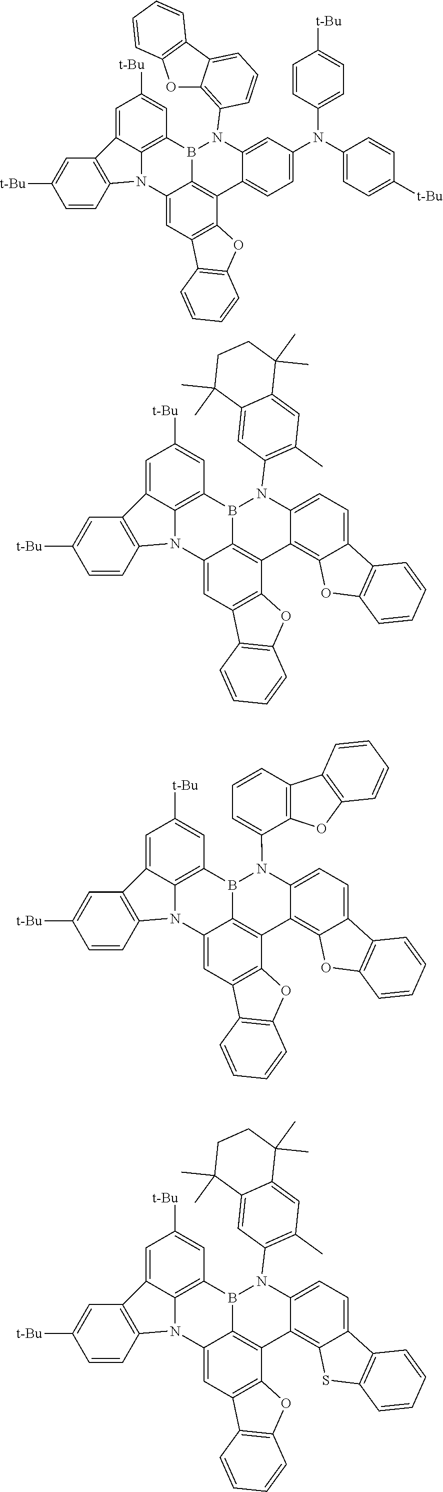 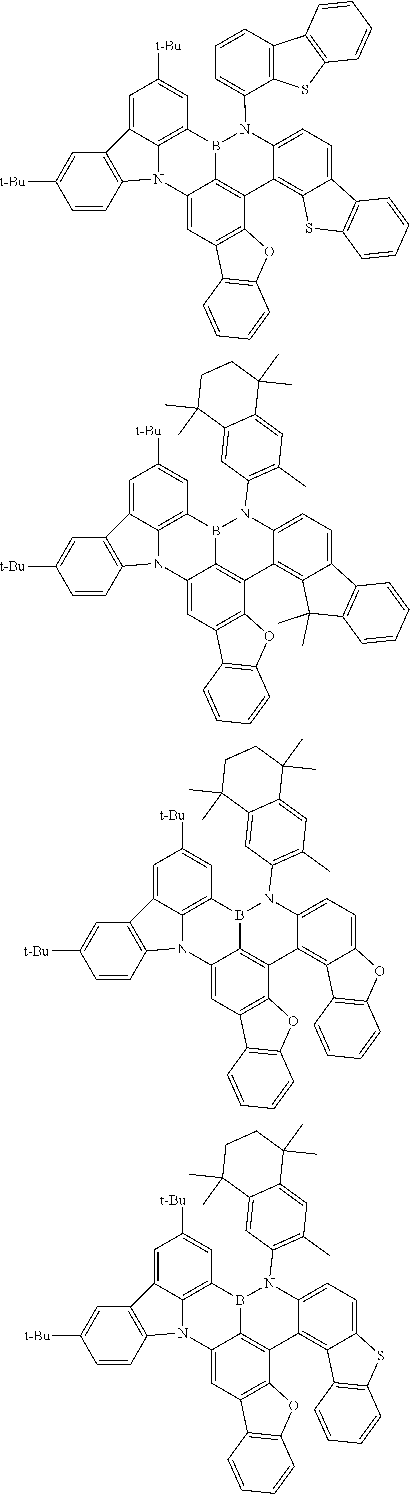 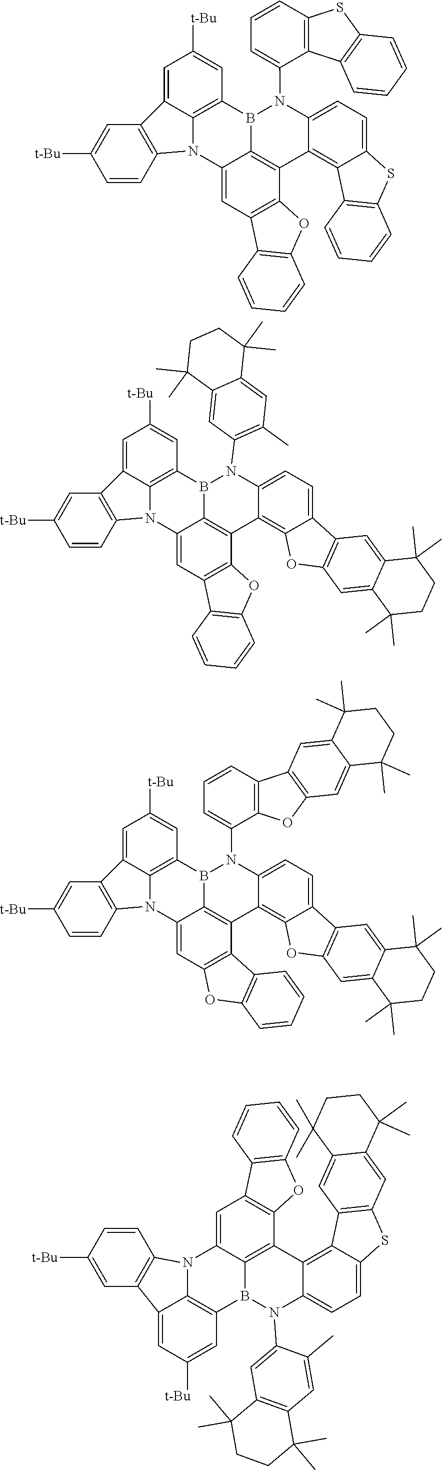 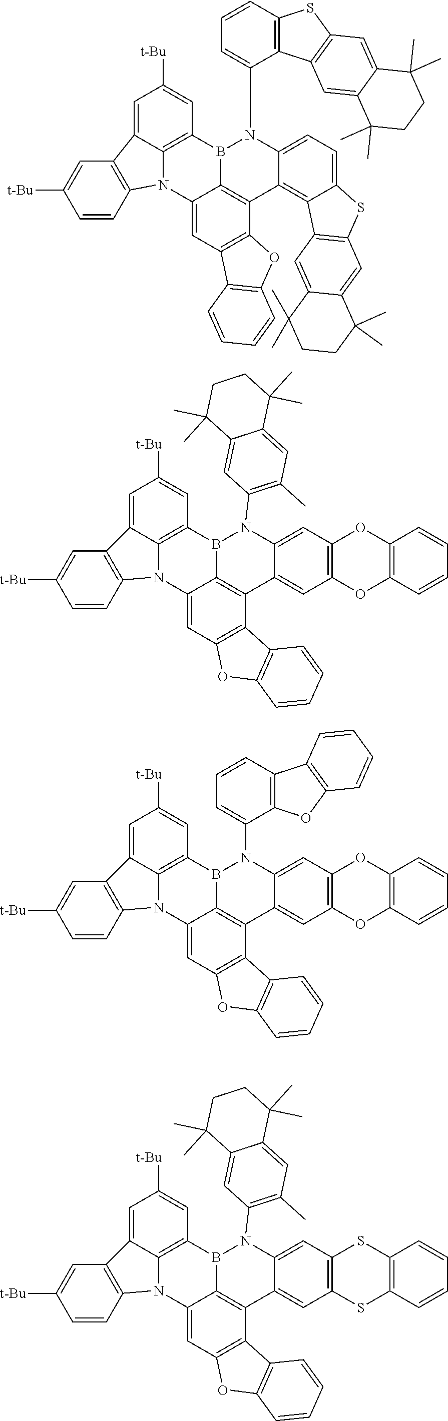 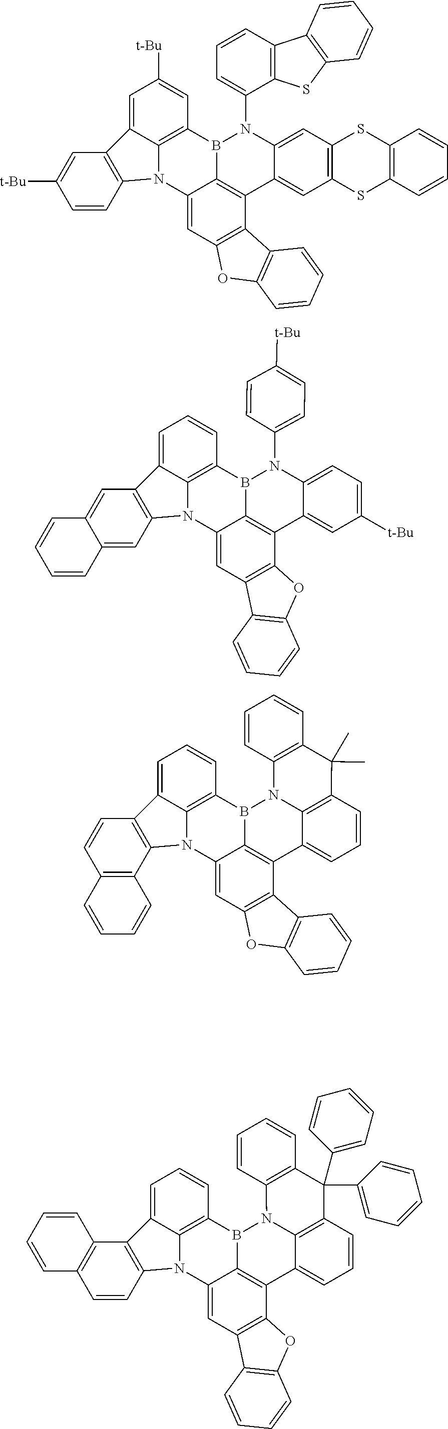 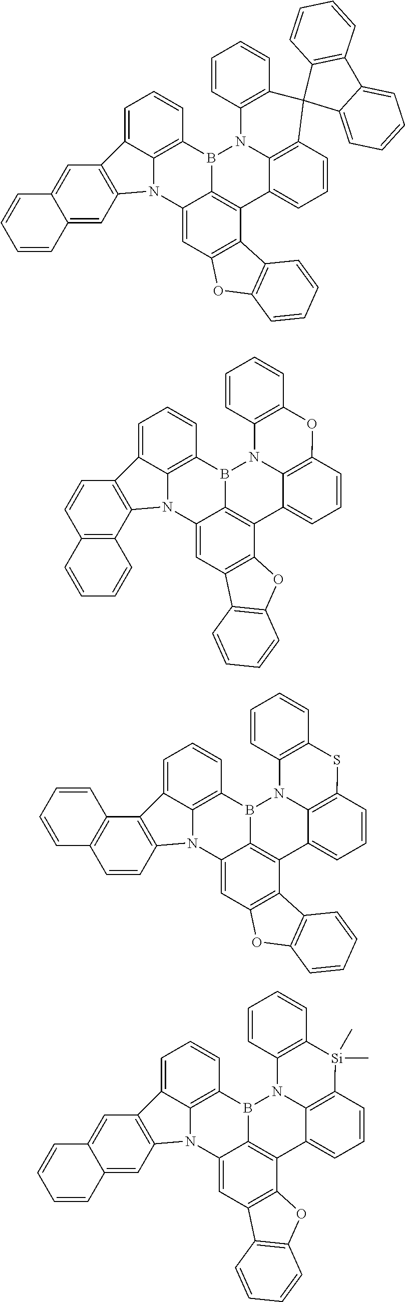 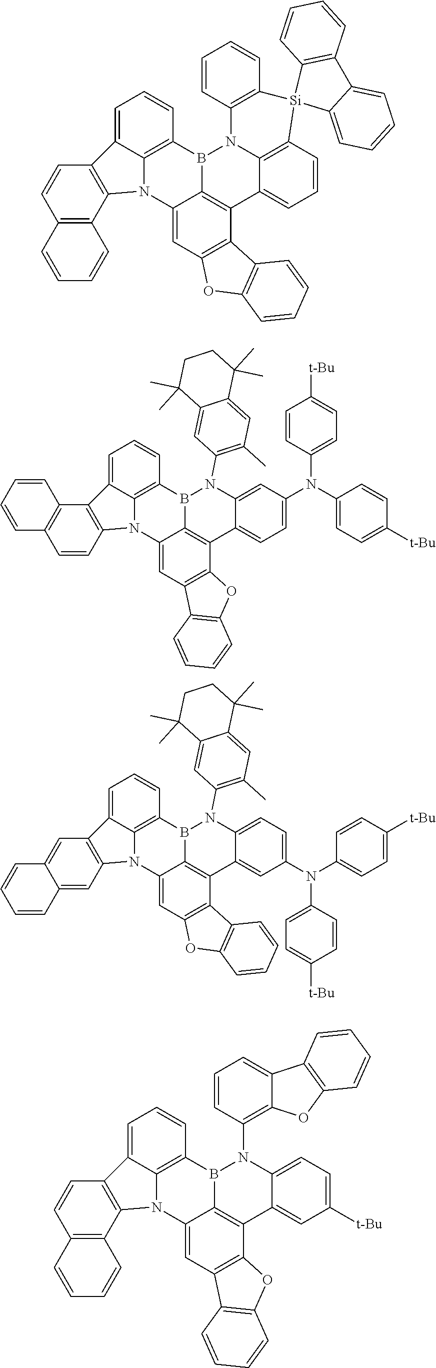 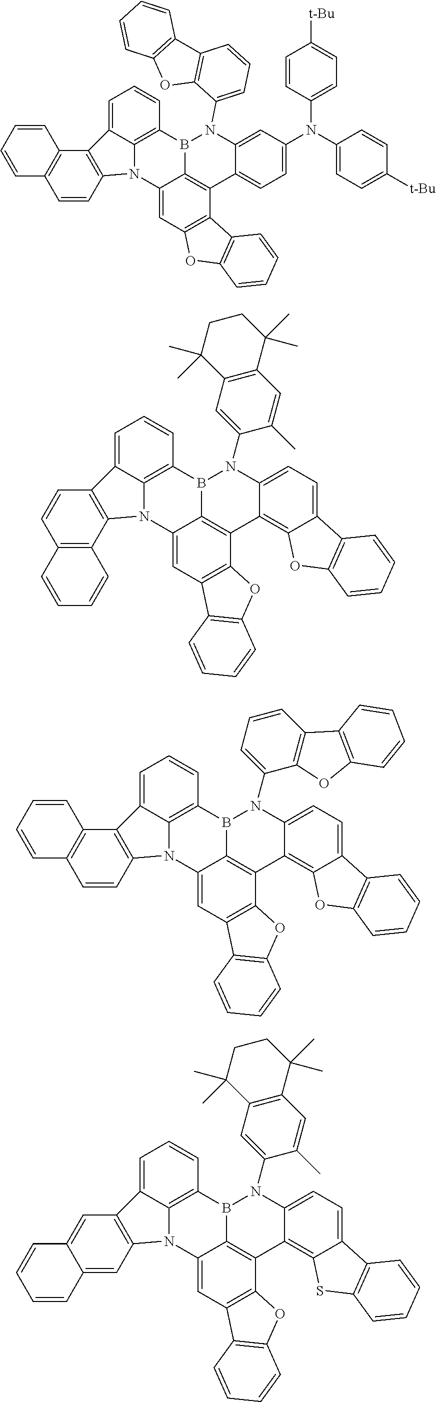 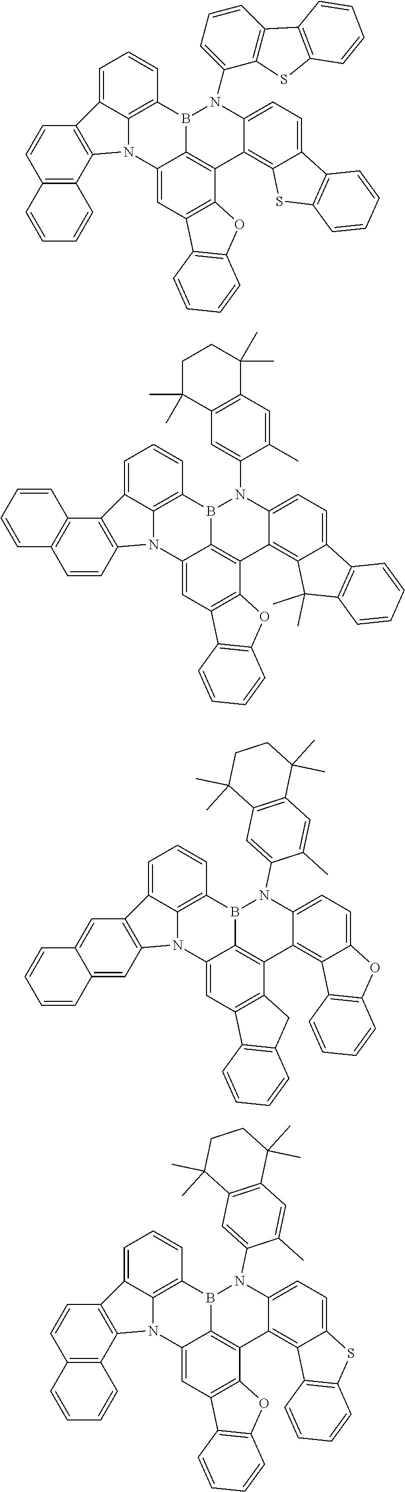 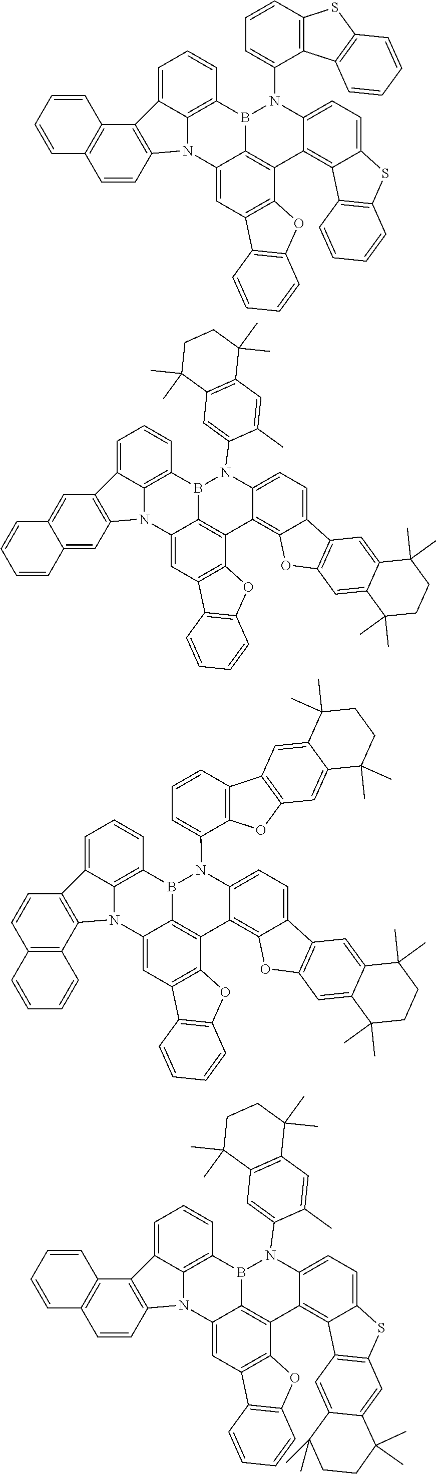 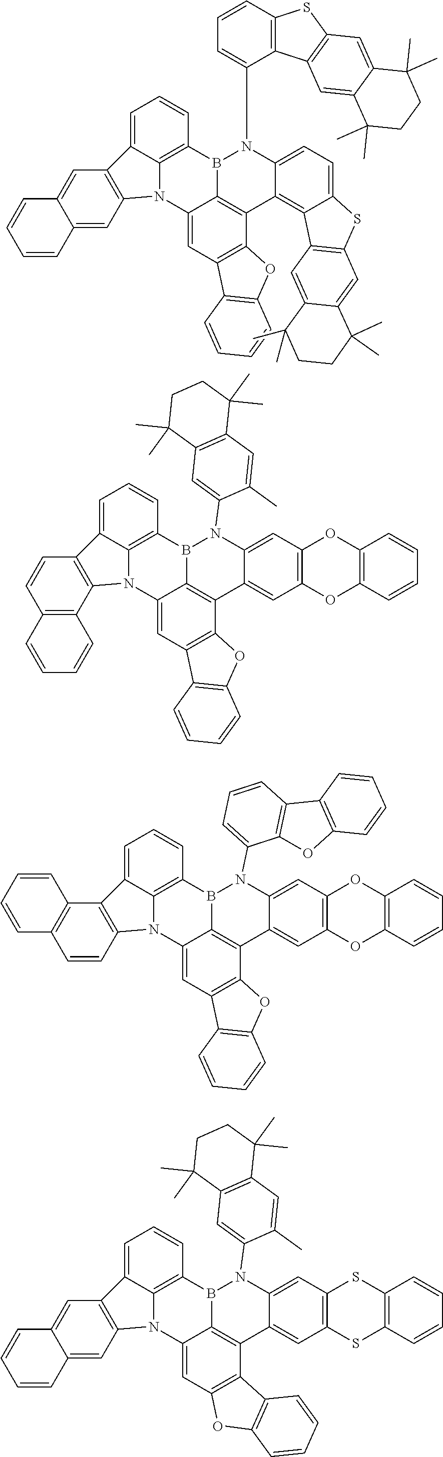 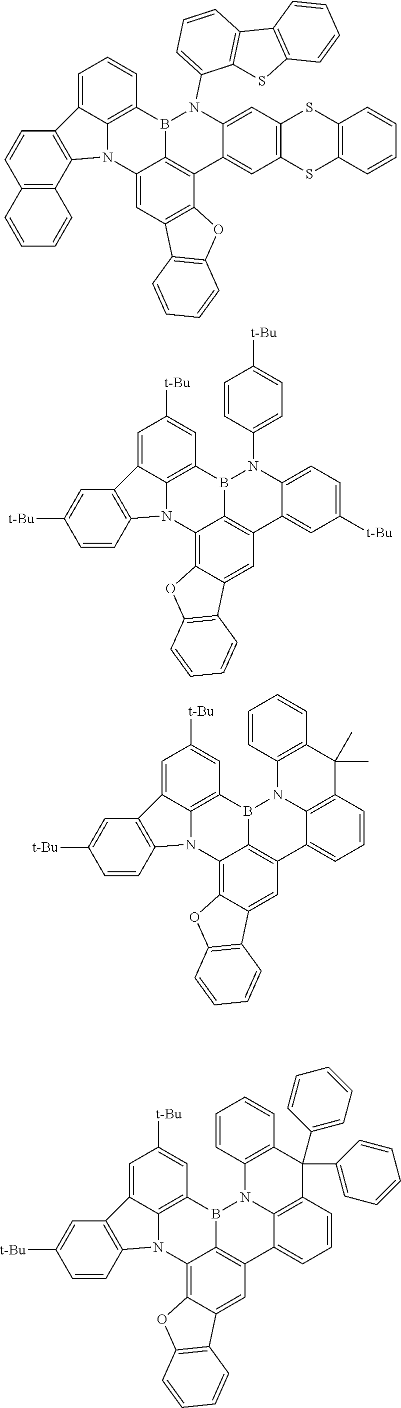 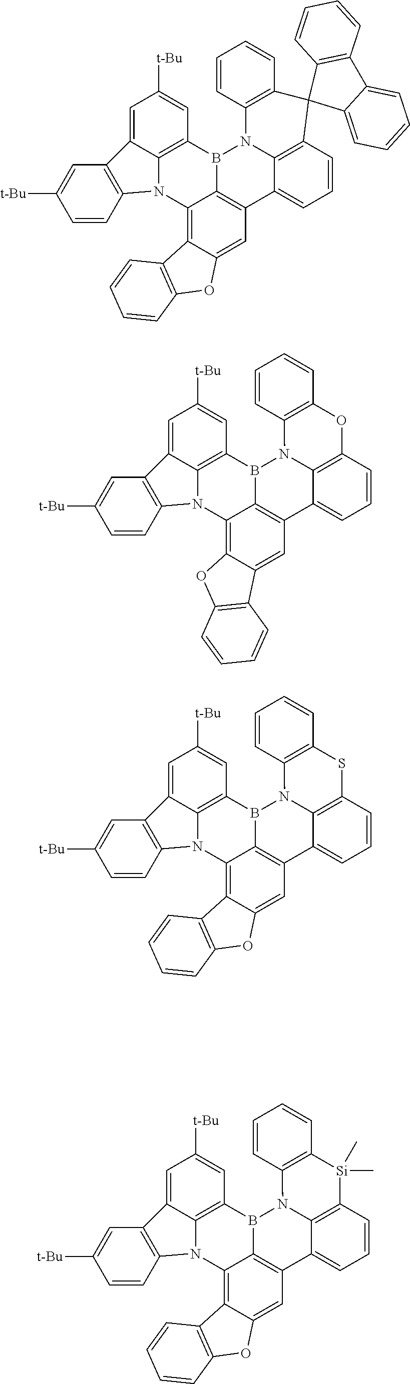 [SMILES: CC(C)(C)c1ccc2c(c1)c1cc(C(C)(C)C)cc3c1n2-c1c2c(cc4oc5ccccc5c14)-c1cccc4c1N(B23)c1ccccc1C41c2ccccc2-c2ccccc21 ; CC(C)(C)c1ccc2c(c1)c1cc(C(C)(C)C)cc3c1n2-c1c2c(cc4c1oc1ccccc14)-c1cccc4c1N(B23)c1ccccc1O4 ; CC(C)(C)c1ccc2c(c1)c1cc(C(C)(C)C)cc3c1n2-c1c2c(cc4oc5ccccc5c14)-c1cccc4c1N(B23)c1ccccc1S4 ; CC(C)(C)c1ccc2c(c1)c1cc(C(C)(C)C)cc3c1n2-c1c2c(cc4oc5ccccc5c14)-c1cccc4c1N(B23)c1ccccc1[Si]4(C)C] 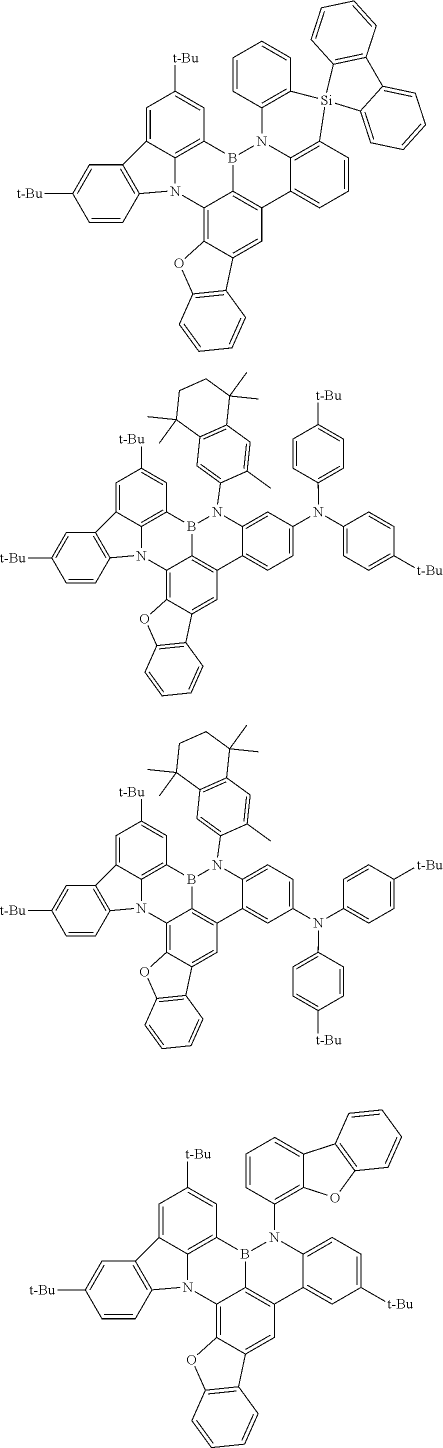 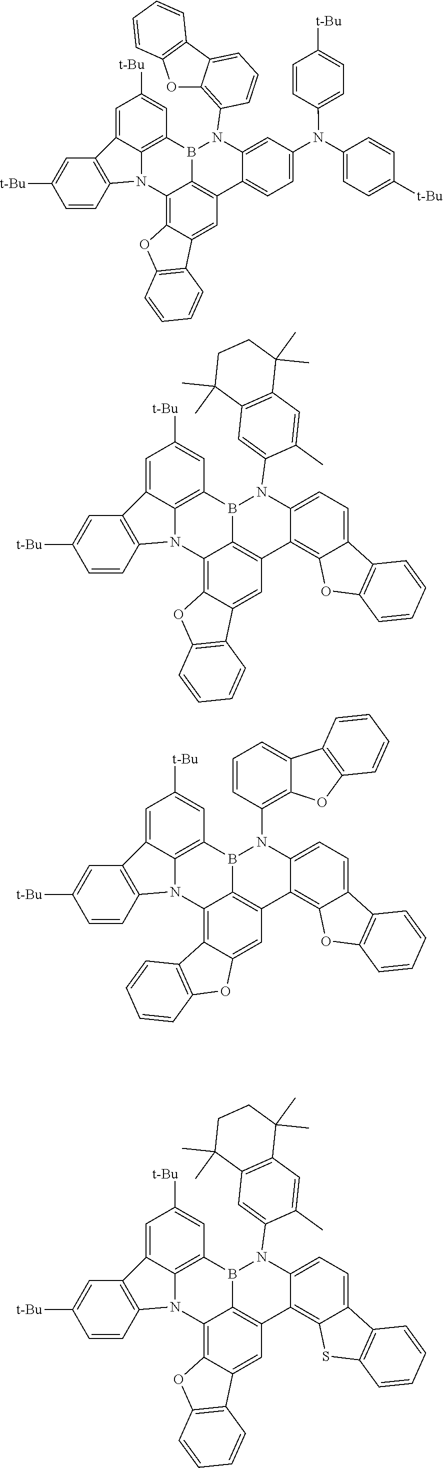 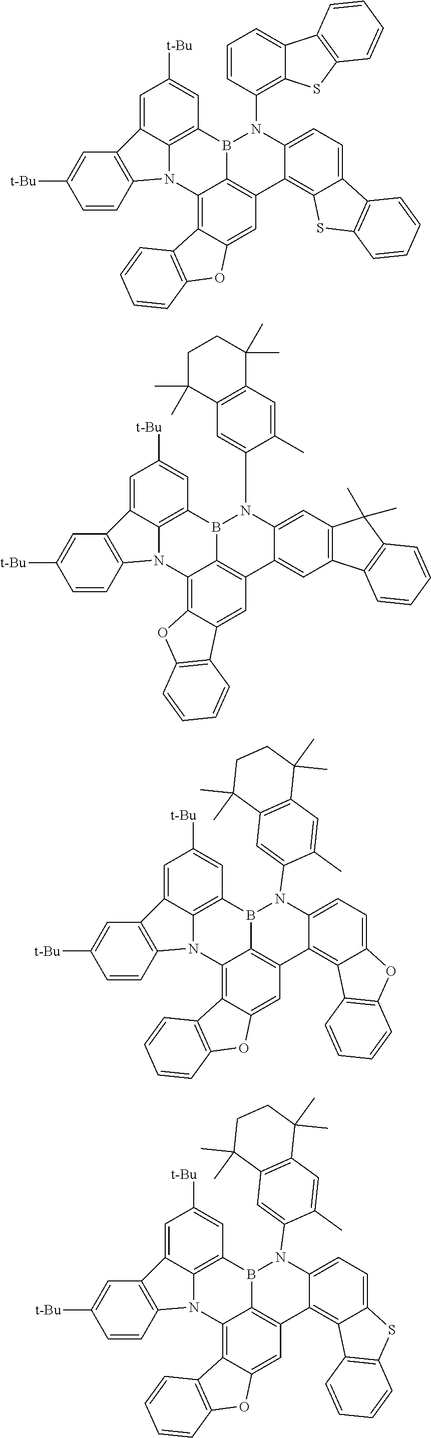 [SMILES: CC(C)(C)c1ccc2c(c1)c1cc(C(C)(C)C)cc3c1n2-c1c2c(cc4oc5ccccc5c14)-c1c(ccc4c1sc1ccccc14)N(c1cccc4c1sc1ccccc14)B23 ; Cc1cc2c(cc1N1B3c4c(cc5c(oc6ccccc65)c4-n4c5ccc(C(C)(C)C)cc5c5cc(C(C)(C)C)cc3c54)-c3cc4c(cc31)C(C)(C)c1ccccc1-4)C(C)(C)CCC2(C)C ; Cc1cc2c(cc1N1B3c4c(cc5oc6ccccc6c5c4-n4c5ccc(C(C)(C)C)cc5c5cc(C(C)(C)C)cc3c54)-c3c1ccc1oc4ccccc4c31)C(C)(C)CCC2(C)C ; Cc1cc2c(cc1N1B3c4c(cc5oc6ccccc6c5c4-n4c5ccc(C(C)(C)C)cc5c5cc(C(C)(C)C)cc3c54)-c3c1ccc1sc4ccccc4c31)C(C)(C)CCC2(C)C] 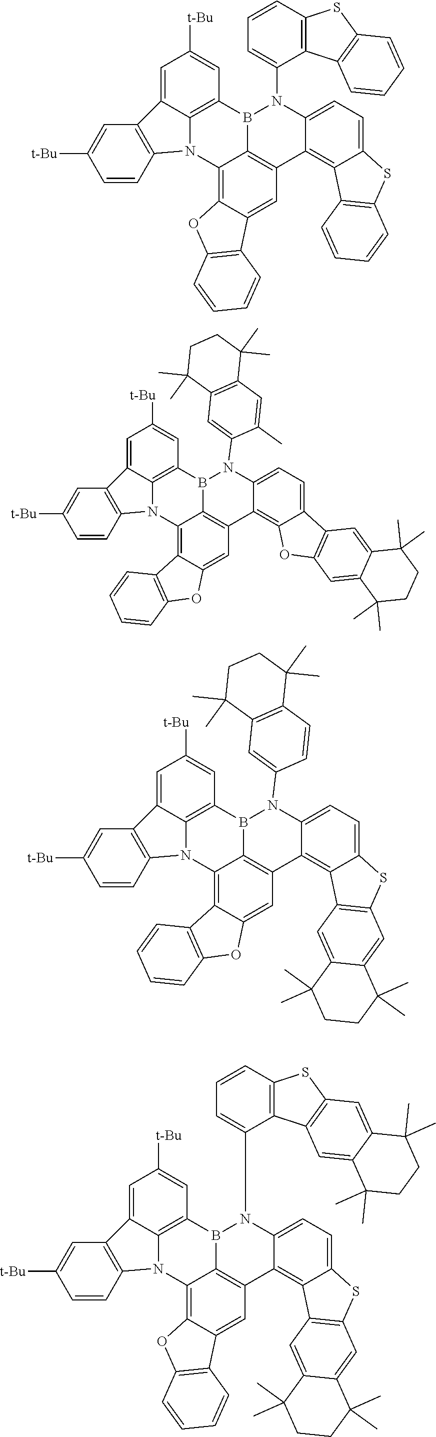 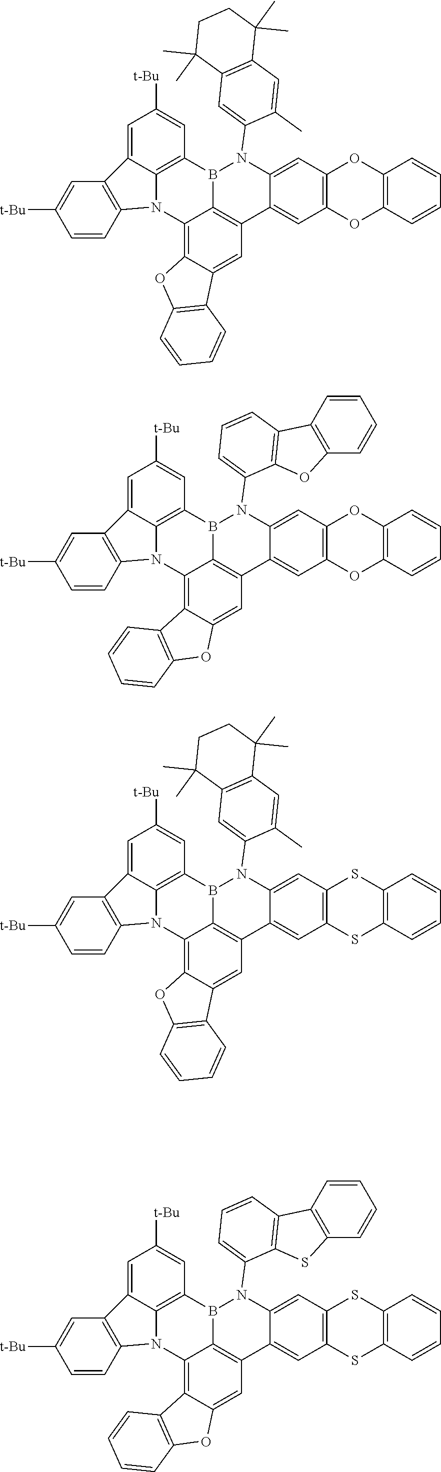 [SMILES: Cc1cc2c(cc1N1B3c4c(cc5c(oc6ccccc65)c4-n4c5ccc(C(C)(C)C)cc5c5cc(C(C)(C)C)cc3c54)-c3cc4c(cc31)Oc1ccccc1O4)C(C)(C)CCC2(C)C ; CC(C)(C)c1ccc2c(c1)c1cc(C(C)(C)C)cc3c1n2-c1c2c(cc4oc5ccccc5c14)-c1cc4c(cc1N(c1cccc5c1oc1ccccc15)B23)Oc1ccccc1O4 ; Cc1cc2c(cc1N1B3c4c(cc5c(oc6ccccc65)c4-n4c5ccc(C(C)(C)C)cc5c5cc(C(C)(C)C)cc3c54)-c3cc4c(cc31)Sc1ccccc1S4)C(C)(C)CCC2(C)C ; CC(C)(C)c1ccc2c(c1)c1cc(C(C)(C)C)cc3c1n2-c1c2c(cc4oc5ccccc5c14)-c1cc4c(cc1N(c1cccc5c1sc1ccccc15)B23)Sc1ccccc1S4] 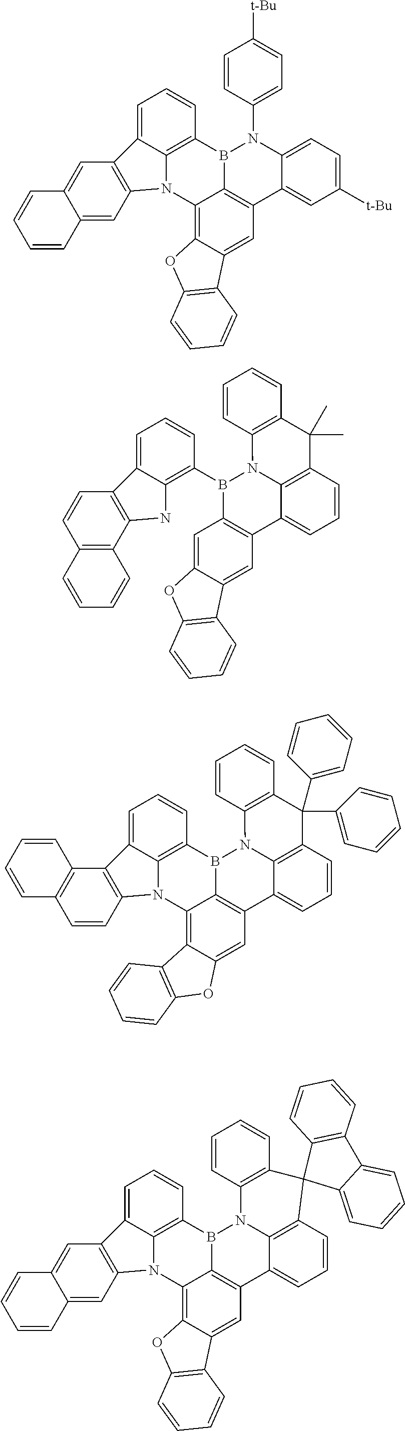 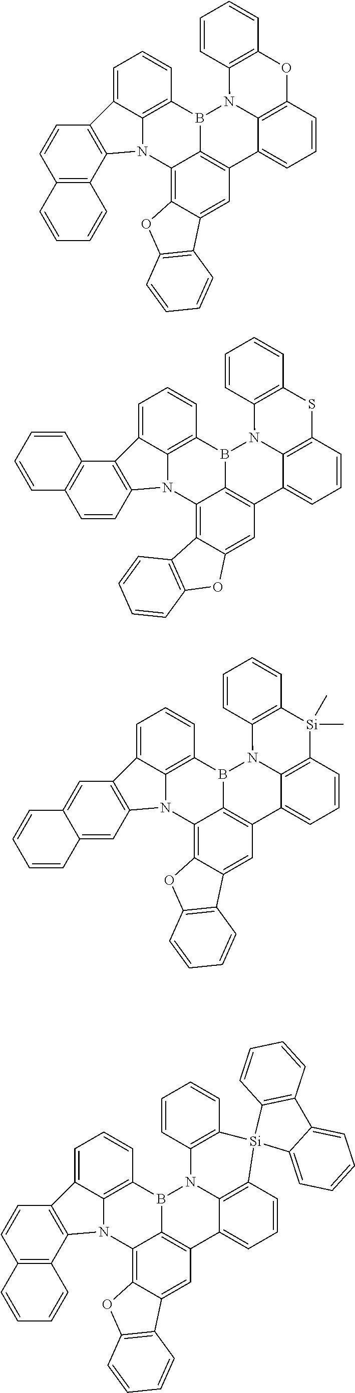 [SMILES: c1ccc2c(c1)Oc1cccc3c1N2B1c2c-3cc3c(oc4ccccc43)c2-n2c3c1cccc3c1ccc3ccccc3c12 ; c1ccc2c(c1)Sc1cccc3c1N2B1c2c-3cc3oc4ccccc4c3c2-n2c3ccc4ccccc4c3c3cccc1c32 ; C[Si]1(C)c2ccccc2N2B3c4c(cc5c(oc6ccccc65)c4-n4c5cc6ccccc6cc5c5cccc3c54)-c3cccc1c32 ; c1ccc2c(c1)-c1ccccc1[Si]21c2ccccc2N2B3c4c(cc5c(oc6ccccc65)c4-n4c5c3cccc5c3ccc5ccccc5c34)-c3cccc1c32] 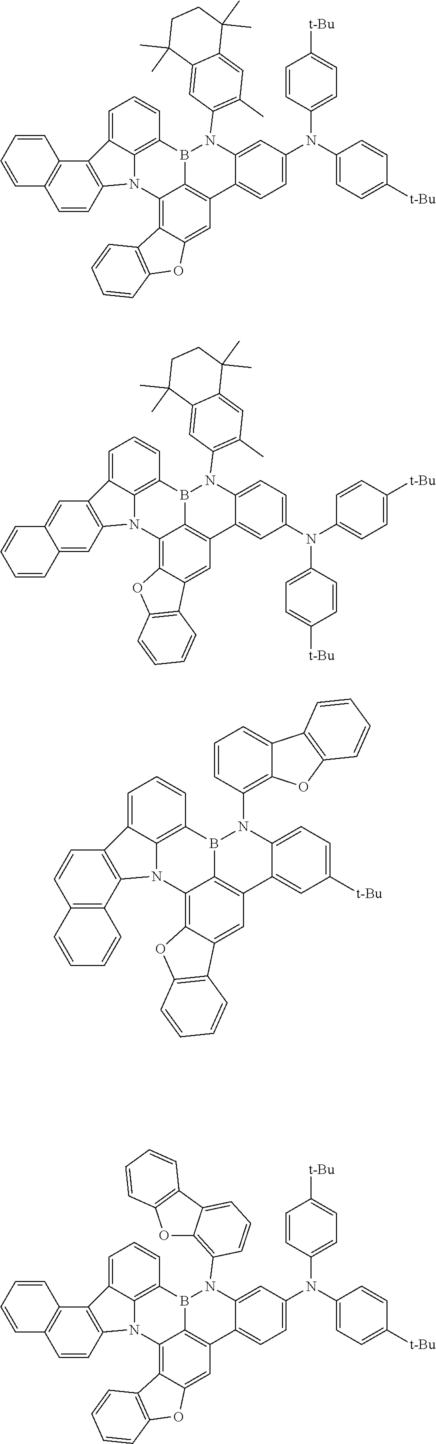 [SMILES: Cc1cc2c(cc1N1B3c4c(cc5oc6ccccc6c5c4-n4c5ccc6ccccc6c5c5cccc3c54)-c3ccc(N(c4ccc(C(C)(C)C)cc4)c4ccc(C(C)(C)C)cc4)cc31)C(C)(C)CCC2(C)C ; Cc1cc2c(cc1N1B3c4c(cc5c(oc6ccccc65)c4-n4c5cc6ccccc6cc5c5cccc3c54)-c3cc(N(c4ccc(C(C)(C)C)cc4)c4ccc(C(C)(C)C)cc4)ccc31)C(C)(C)CCC2(C)C ; CC(C)(C)c1ccc2c(c1)-c1cc3c(oc4ccccc43)c3c1B(c1cccc4c5ccc6ccccc6c5n-3c14)N2c1cccc2c1oc1ccccc12 ; CC(C)(C)c1ccc(N(c2ccc(C(C)(C)C)cc2)c2ccc3c(c2)N(c2cccc4c2oc2ccccc24)B2c4c-3cc3oc5ccccc5c3c4-n3c4ccc5ccccc5c4c4cccc2c43)cc1] 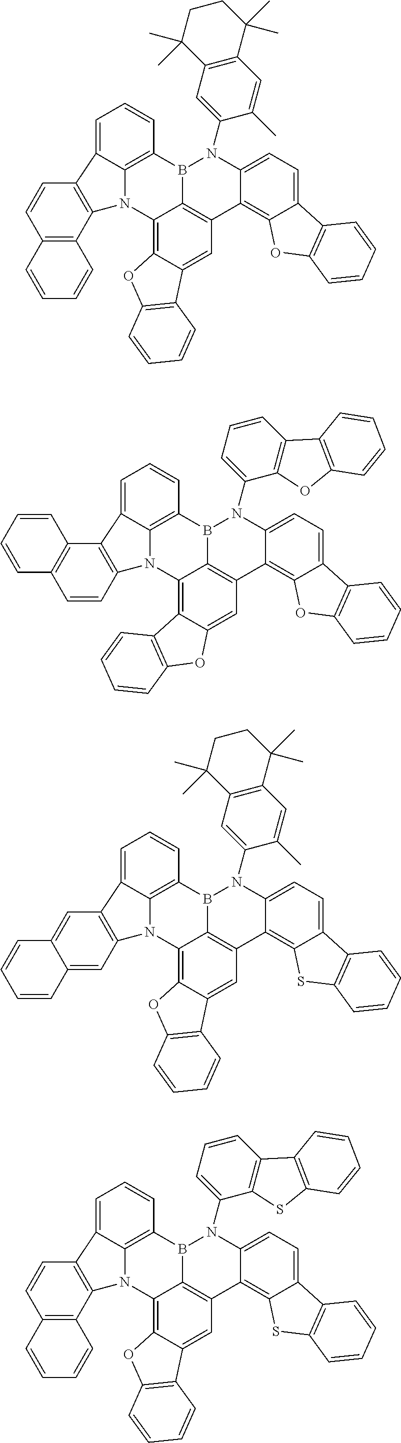 [SMILES: Cc1cc2c(cc1N1B3c4c(cc5c(oc6ccccc65)c4-n4c5c3cccc5c3ccc5ccccc5c34)-c3c1ccc1c3oc3ccccc31)C(C)(C)CCC2(C)C ; c1ccc2c(c1)ccc1c2c2cccc3c2n1-c1c2c(cc4oc5ccccc5c14)-c1c(ccc4c1oc1ccccc14)N(c1cccc4c1oc1ccccc14)B23 ; Cc1cc2c(cc1N1B3c4c(cc5c(oc6ccccc65)c4-n4c5cc6ccccc6cc5c5cccc3c54)-c3c1ccc1c3sc3ccccc31)C(C)(C)CCC2(C)C ; c1ccc2c(c1)ccc1c3cccc4c3n(c21)-c1c2c(cc3c1oc1ccccc13)-c1c(ccc3c1sc1ccccc13)N(c1cccc3c1sc1ccccc13)B24] 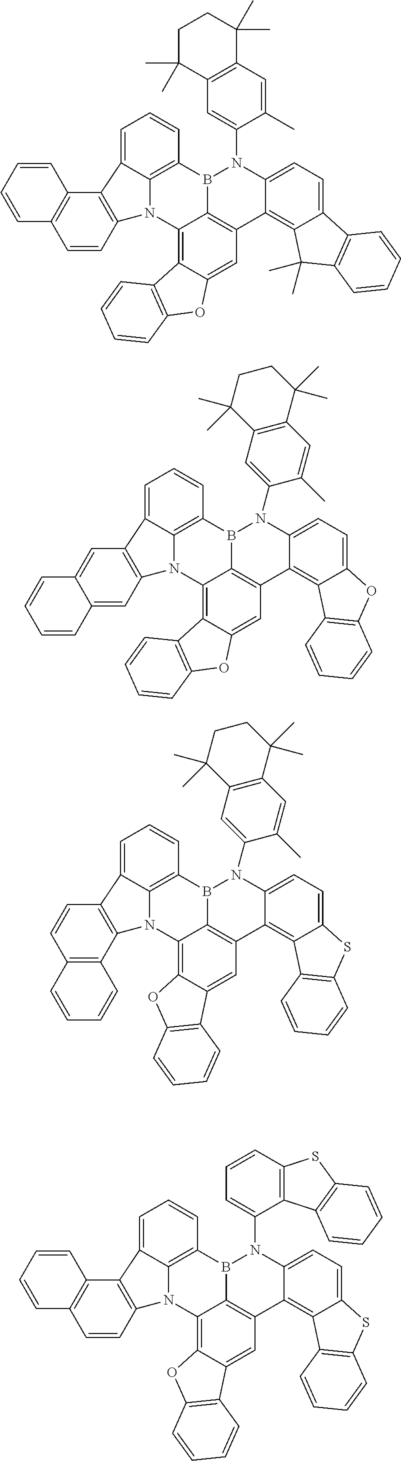 [SMILES: Cc1cc2c(cc1N1B3c4c(cc5oc6ccccc6c5c4-n4c5ccc6ccccc6c5c5cccc3c54)-c3c1ccc1c3C(C)(C)c3ccccc3-1)C(C)(C)CCC2(C)C ; Cc1cc2c(cc1N1B3c4c(cc5oc6ccccc6c5c4-n4c5cc6ccccc6cc5c5cccc3c54)-c3c1ccc1oc4ccccc4c31)C(C)(C)CCC2(C)C ; Cc1cc2c(cc1N1B3c4c(cc5c(oc6ccccc65)c4-n4c5c3cccc5c3ccc5ccccc5c34)-c3c1ccc1sc4ccccc4c31)C(C)(C)CCC2(C)C ; c1ccc2c(c1)ccc1c2c2cccc3c2n1-c1c2c(cc4c1oc1ccccc14)-c1c(ccc4sc5ccccc5c14)N(c1cccc4sc5ccccc5c14)B23] 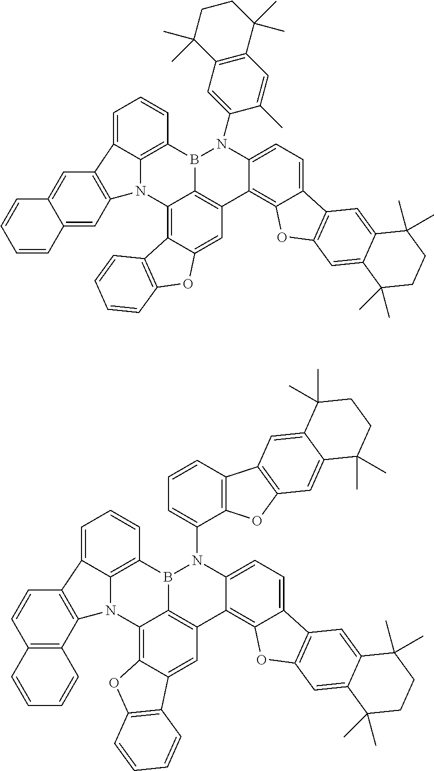 [SMILES: Cc1cc2c(cc1N1B3c4c(cc5oc6ccccc6c5c4-n4c5cc6ccccc6cc5c5cccc3c54)-c3c1ccc1c3oc3cc4c(cc31)C(C)(C)CCC4(C)C)C(C)(C)CCC2(C)C ; CC1(C)CCC(C)(C)c2cc3c(cc21)oc1c(N2B4c5c(cc6c(oc7ccccc76)c5-n5c6c4cccc6c4ccc6ccccc6c45)-c4c2ccc2c4oc4cc5c(cc42)C(C)(C)CCC5(C)C)cccc13] 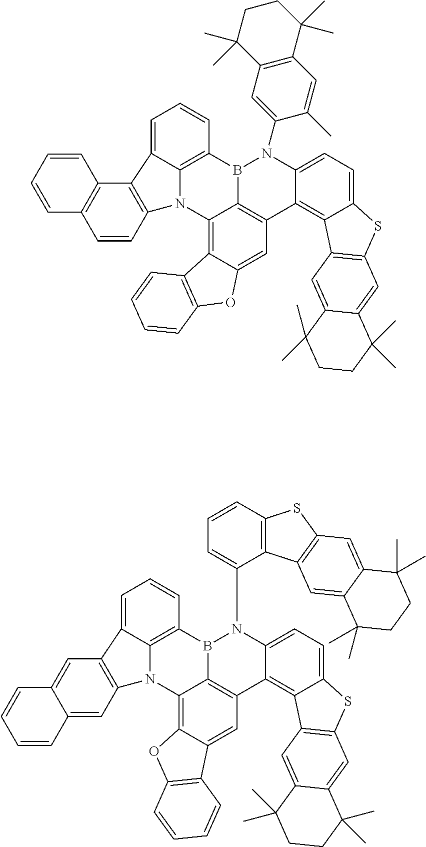 [SMILES: Cc1cc2c(cc1N1B3c4c(cc5oc6ccccc6c5c4-n4c5ccc6ccccc6c5c5cccc3c54)-c3c1ccc1sc4cc5c(cc4c31)C(C)(C)CCC5(C)C)C(C)(C)CCC2(C)C ; CC1(C)CCC(C)(C)c2cc3c(cc21)sc1cccc(N2B4c5c(cc6c(oc7ccccc76)c5-n5c6cc7ccccc7cc6c6cccc4c65)-c4c2ccc2sc5cc6c(cc5c42)C(C)(C)CCC6(C)C)c13] 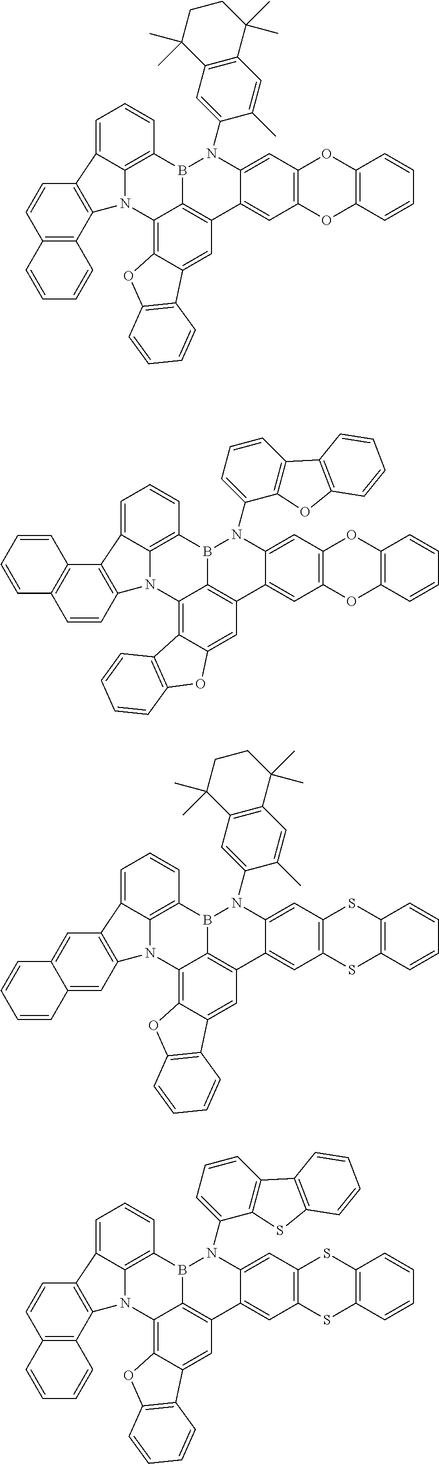 [SMILES: Cc1cc2c(cc1N1B3c4c(cc5c(oc6ccccc65)c4-n4c5c3cccc5c3ccc5ccccc5c34)-c3cc4c(cc31)Oc1ccccc1O4)C(C)(C)CCC2(C)C ; c1ccc2c(c1)Oc1cc3c(cc1O2)N(c1cccc2c1oc1ccccc12)B1c2c-3cc3oc4ccccc4c3c2-n2c3ccc4ccccc4c3c3cccc1c32 ; Cc1cc2c(cc1N1B3c4c(cc5c(oc6ccccc65)c4-n4c5cc6ccccc6cc5c5cccc3c54)-c3cc4c(cc31)Sc1ccccc1S4)C(C)(C)CCC2(C)C ; c1ccc2c(c1)Sc1cc3c(cc1S2)N(c1cccc2c1sc1ccccc12)B1c2c-3cc3c(oc4ccccc43)c2-n2c3c1cccc3c1ccc3ccccc3c12] 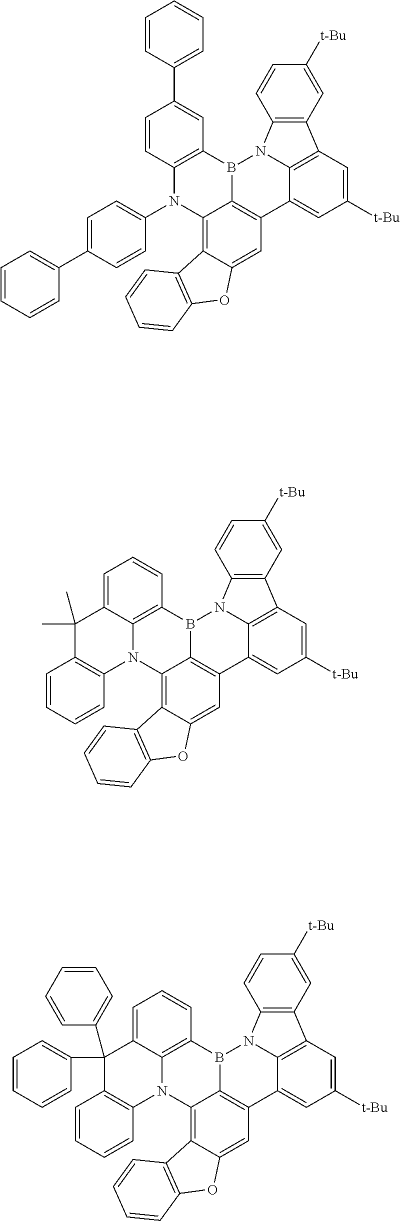 [SMILES: CC(C)(C)c1ccc2c(c1)c1cc(C(C)(C)C)cc3c1n2B1c2cc(-c4ccccc4)ccc2N(c2ccc(-c4ccccc4)cc2)c2c1c-3cc1oc3ccccc3c21 ; CC(C)(C)c1ccc2c(c1)c1cc(C(C)(C)C)cc3c1n2B1c2cccc4c2N(c2ccccc2C4(C)C)c2c1c-3cc1oc3ccccc3c21 ; CC(C)(C)c1ccc2c(c1)c1cc(C(C)(C)C)cc3c1n2B1c2cccc4c2N(c2ccccc2C4(c2ccccc2)c2ccccc2)c2c1c-3cc1oc3ccccc3c21] 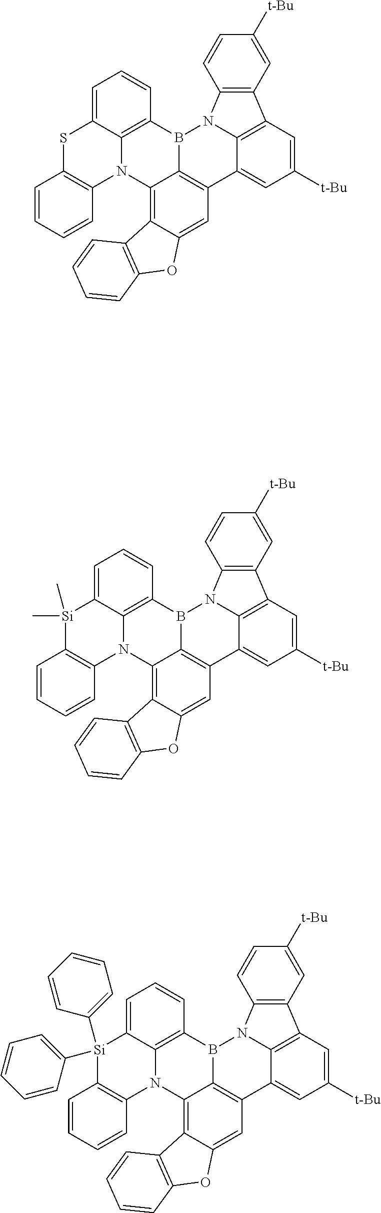 [SMILES: CC(C)(C)c1ccc2c(c1)c1cc(C(C)(C)C)cc3c1n2B1c2cccc4c2N(c2ccccc2S4)c2c1c-3cc1oc3ccccc3c21 ; CC(C)(C)c1ccc2c(c1)c1cc(C(C)(C)C)cc3c1n2B1c2cccc4c2N(c2ccccc2[Si]4(C)C)c2c1c-3cc1oc3ccccc3c21 ; CC(C)(C)c1ccc2c(c1)c1cc(C(C)(C)C)cc3c1n2B1c2cccc4c2N(c2ccccc2[Si]4(c2ccccc2)c2ccccc2)c2c1c-3cc1oc3ccccc3c21] 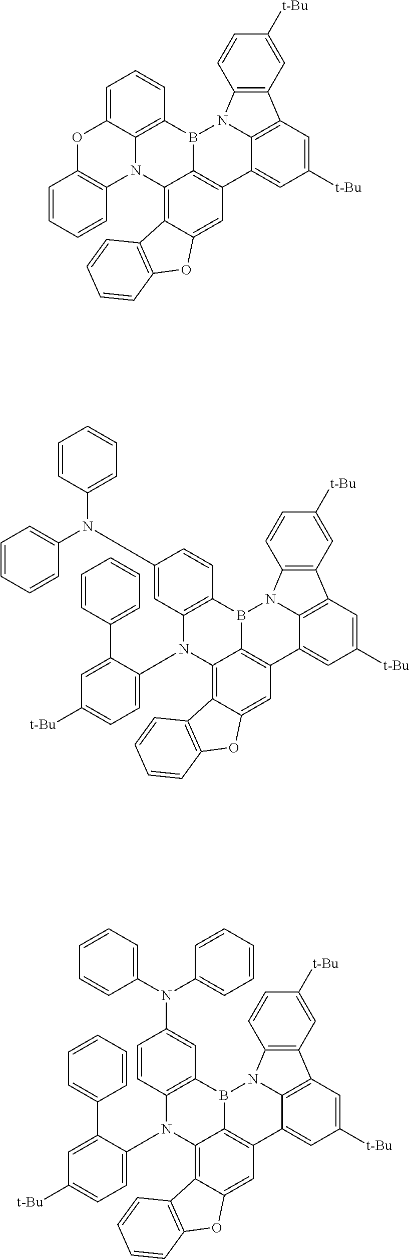 [SMILES: CC(C)(C)c1ccc2c(c1)c1cc(C(C)(C)C)cc3c1n2B1c2cccc4c2N(c2ccccc2O4)c2c1c-3cc1oc3ccccc3c21 ; CC(C)(C)c1ccc(N2c3cc(N(c4ccccc4)c4ccccc4)ccc3B3c4c(cc5oc6ccccc6c5c42)-c2cc(C(C)(C)C)cc4c5cc(C(C)(C)C)ccc5n3c24)c(-c2ccccc2)c1 ; CC(C)(C)c1ccc(N2c3ccc(N(c4ccccc4)c4ccccc4)cc3B3c4c(cc5oc6ccccc6c5c42)-c2cc(C(C)(C)C)cc4c5cc(C(C)(C)C)ccc5n3c24)c(-c2ccccc2)c1] 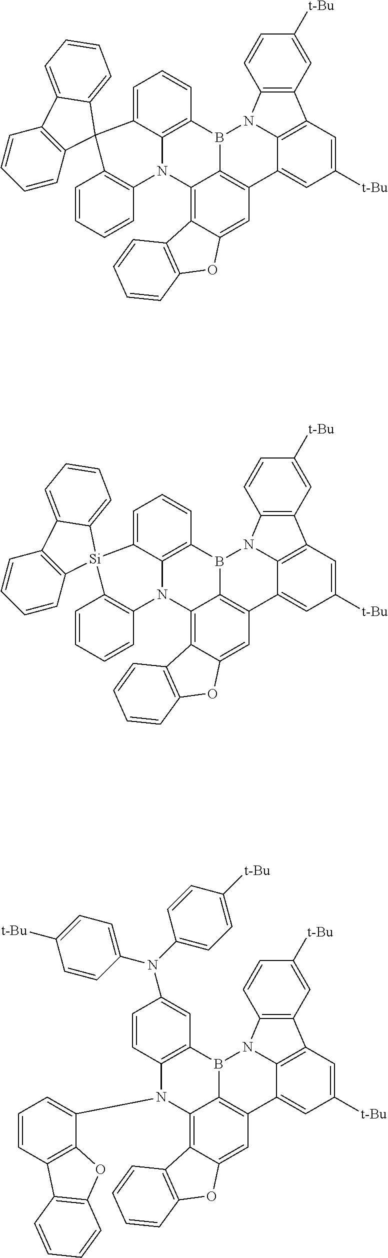 [SMILES: CC(C)(C)c1ccc2c(c1)c1cc(C(C)(C)C)cc3c1n2B1c2cccc4c2N(c2ccccc2C42c4ccccc4-c4ccccc42)c2c1c-3cc1oc3ccccc3c21 ; CC(C)(C)c1ccc2c(c1)c1cc(C(C)(C)C)cc3c1n2B1c2cccc4c2N(c2ccccc2[Si]42c4ccccc4-c4ccccc42)c2c1c-3cc1oc3ccccc3c21 ; CC(C)(C)c1ccc(N(c2ccc(C(C)(C)C)cc2)c2ccc3c(c2)B2c4c(cc5oc6ccccc6c5c4N3c3cccc4c3oc3ccccc34)-c3cc(C(C)(C)C)cc4c5cc(C(C)(C)C)ccc5n2c34)cc1] 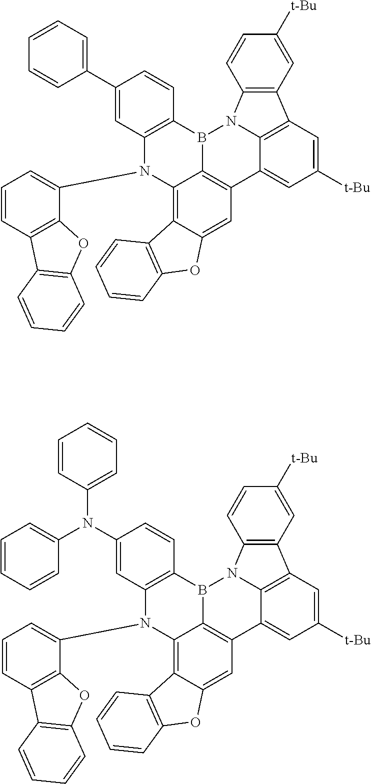 [SMILES: CC(C)(C)c1ccc2c(c1)c1cc(C(C)(C)C)cc3c1n2B1c2ccc(-c4ccccc4)cc2N(c2cccc4c2oc2ccccc24)c2c1c-3cc1oc3ccccc3c21 ; CC(C)(C)c1ccc2c(c1)c1cc(C(C)(C)C)cc3c1n2B1c2ccc(N(c4ccccc4)c4ccccc4)cc2N(c2cccc4c2oc2ccccc24)c2c1c-3cc1oc3ccccc3c21] 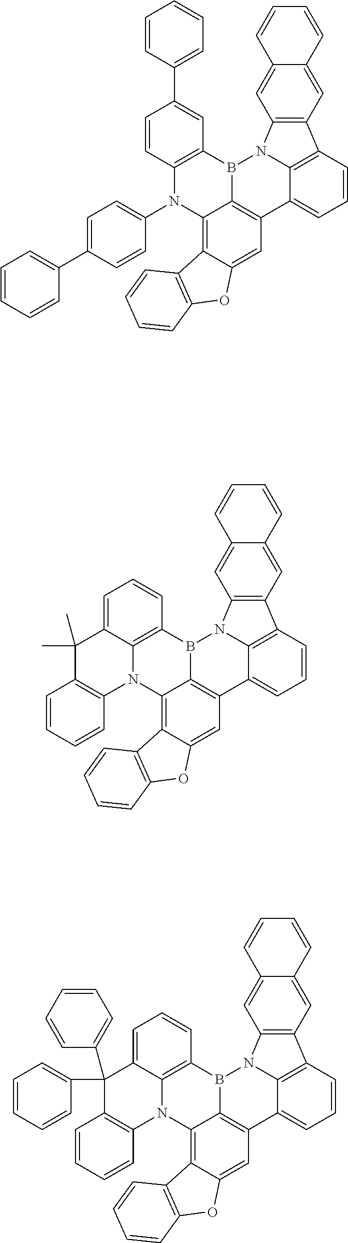 [SMILES: c1ccc(-c2ccc(N3c4ccc(-c5ccccc5)cc4B4c5c(cc6oc7ccccc7c6c53)-c3cccc5c6cc7ccccc7cc6n4c35)cc2)cc1 ; CC1(C)c2ccccc2N2c3c(cccc31)B1c3c(cc4oc5ccccc5c4c32)-c2cccc3c4cc5ccccc5cc4n1c23 ; c1ccc(C2(c3ccccc3)c3ccccc3N3c4c(cccc42)B2c4c(cc5oc6ccccc6c5c43)-c3cccc4c5cc6ccccc6cc5n2c34)cc1] 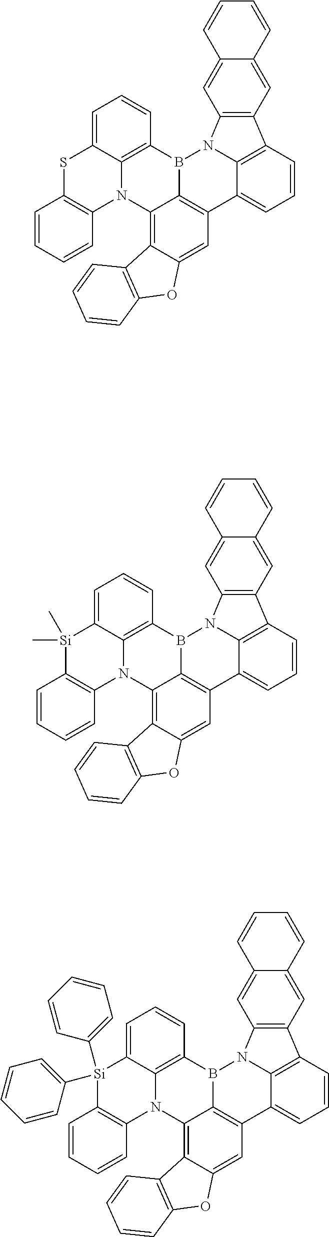 [SMILES: c1ccc2c(c1)Sc1cccc3c1N2c1c2c(cc4oc5ccccc5c14)-c1cccc4c5cc6ccccc6cc5n(c14)B32 ; C[Si]1(C)c2ccccc2N2c3c(cccc31)B1c3c(cc4oc5ccccc5c4c32)-c2cccc3c4cc5ccccc5cc4n1c23 ; c1ccc([Si]2(c3ccccc3)c3ccccc3N3c4c(cccc42)B2c4c(cc5oc6ccccc6c5c43)-c3cccc4c5cc6ccccc6cc5n2c34)cc1] 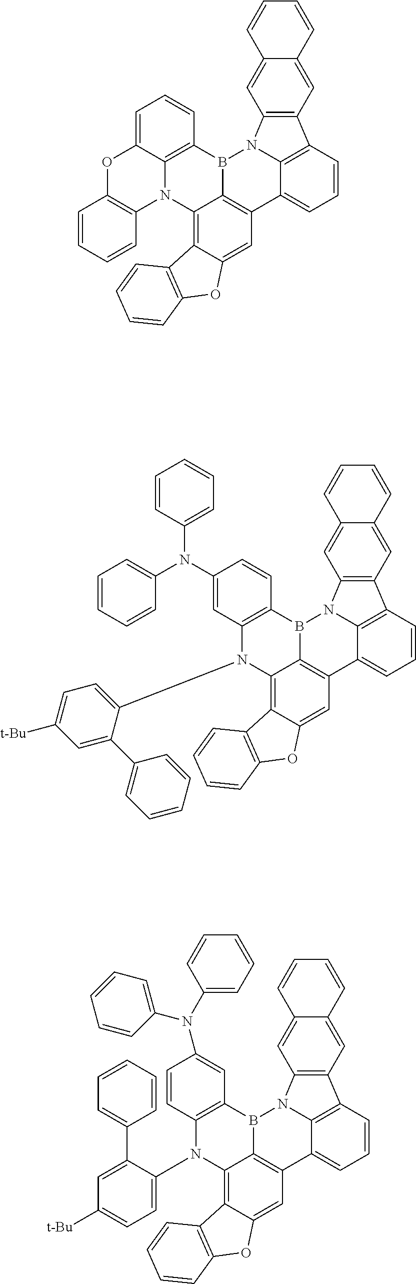 [SMILES: c1ccc2c(c1)Oc1cccc3c1N2c1c2c(cc4oc5ccccc5c14)-c1cccc4c5cc6ccccc6cc5n(c14)B32 ; CC(C)(C)c1ccc(N2c3cc(N(c4ccccc4)c4ccccc4)ccc3B3c4c(cc5oc6ccccc6c5c42)-c2cccc4c5cc6ccccc6cc5n3c24)c(-c2ccccc2)c1 ; CC(C)(C)c1ccc(N2c3ccc(N(c4ccccc4)c4ccccc4)cc3B3c4c(cc5oc6ccccc6c5c42)-c2cccc4c5cc6ccccc6cc5n3c24)c(-c2ccccc2)c1] 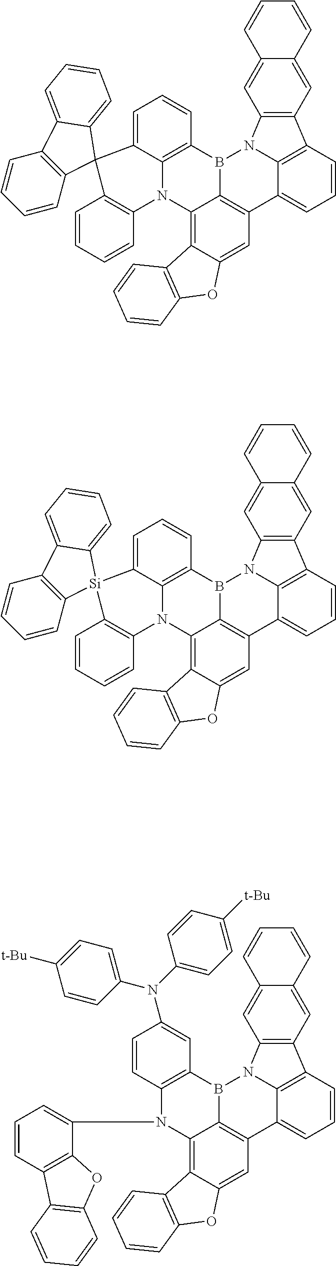 [SMILES: c1ccc2c(c1)-c1ccccc1C21c2ccccc2N2c3c(cccc31)B1c3c(cc4oc5ccccc5c4c32)-c2cccc3c4cc5ccccc5cc4n1c23 ; c1ccc2c(c1)-c1ccccc1[Si]21c2ccccc2N2c3c(cccc31)B1c3c(cc4oc5ccccc5c4c32)-c2cccc3c4cc5ccccc5cc4n1c23 ; CC(C)(C)c1ccc(N(c2ccc(C(C)(C)C)cc2)c2ccc3c(c2)B2c4c(cc5oc6ccccc6c5c4N3c3cccc4c3oc3ccccc34)-c3cccc4c5cc6ccccc6cc5n2c34)cc1] 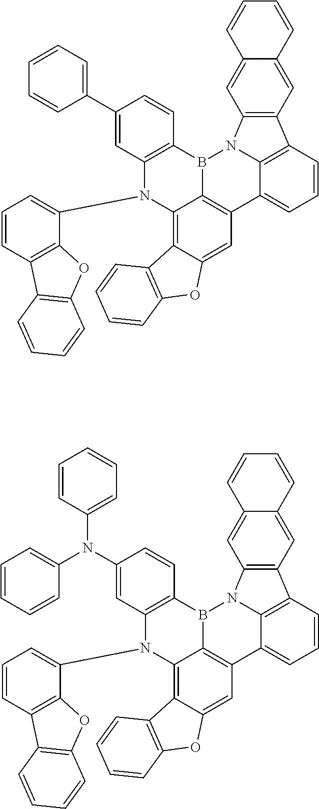 [SMILES: c1ccc(-c2ccc3c(c2)N(c2cccc4c2oc2ccccc24)c2c4c(cc5oc6ccccc6c25)-c2cccc5c6cc7ccccc7cc6n(c25)B34)cc1 ; c1ccc(N(c2ccccc2)c2ccc3c(c2)N(c2cccc4c2oc2ccccc24)c2c4c(cc5oc6ccccc6c25)-c2cccc5c6cc7ccccc7cc6n(c25)B34)cc1] 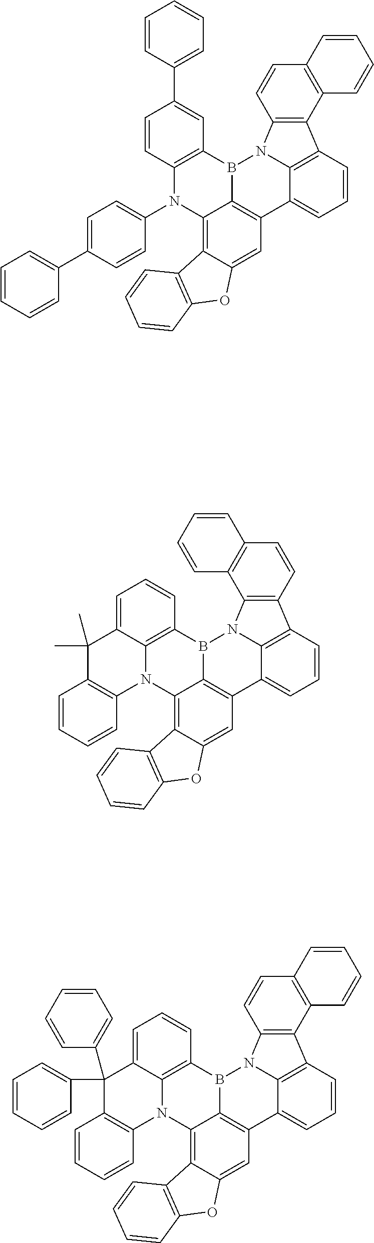 [SMILES: c1ccc(-c2ccc(N3c4ccc(-c5ccccc5)cc4B4c5c(cc6oc7ccccc7c6c53)-c3cccc5c6c7ccccc7ccc6n4c35)cc2)cc1 ; CC1(C)c2ccccc2N2c3c(cccc31)B1c3c(cc4oc5ccccc5c4c32)-c2cccc3c4ccc5ccccc5c4n1c23 ; c1ccc(C2(c3ccccc3)c3ccccc3N3c4c(cccc42)B2c4c(cc5oc6ccccc6c5c43)-c3cccc4c5c6ccccc6ccc5n2c34)cc1] 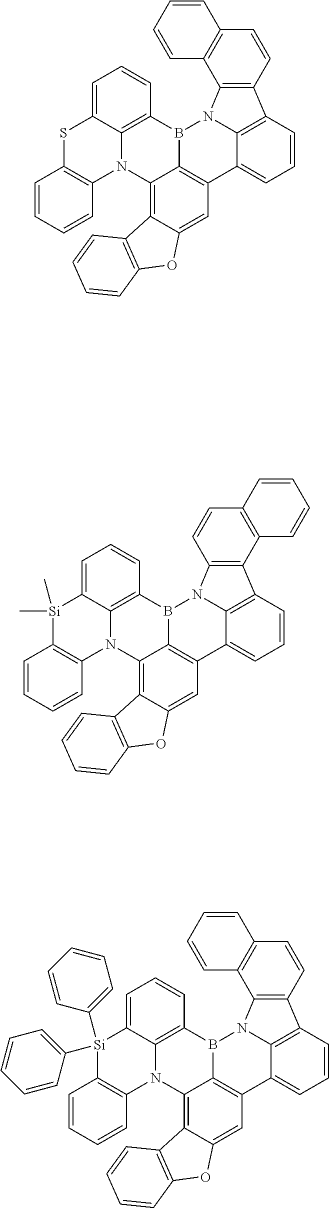 [SMILES: c1ccc2c(c1)Sc1cccc3c1N2c1c2c(cc4oc5ccccc5c14)-c1cccc4c5ccc6ccccc6c5n(c14)B32 ; C[Si]1(C)c2ccccc2N2c3c(cccc31)B1c3c(cc4oc5ccccc5c4c32)-c2cccc3c4c5ccccc5ccc4n1c23 ; c1ccc([Si]2(c3ccccc3)c3ccccc3N3c4c(cccc42)B2c4c(cc5oc6ccccc6c5c43)-c3cccc4c5ccc6ccccc6c5n2c34)cc1] 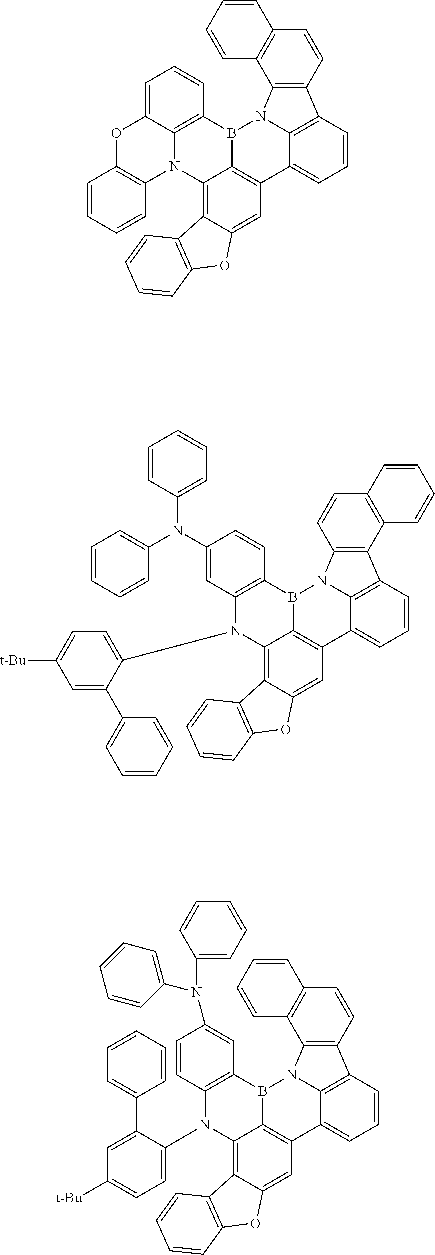 [SMILES: c1ccc2c(c1)Oc1cccc3c1N2c1c2c(cc4oc5ccccc5c14)-c1cccc4c5ccc6ccccc6c5n(c14)B32 ; CC(C)(C)c1ccc(N2c3cc(N(c4ccccc4)c4ccccc4)ccc3B3c4c(cc5oc6ccccc6c5c42)-c2cccc4c5c6ccccc6ccc5n3c24)c(-c2ccccc2)c1 ; CC(C)(C)c1ccc(N2c3ccc(N(c4ccccc4)c4ccccc4)cc3B3c4c(cc5oc6ccccc6c5c42)-c2cccc4c5ccc6ccccc6c5n3c24)c(-c2ccccc2)c1] 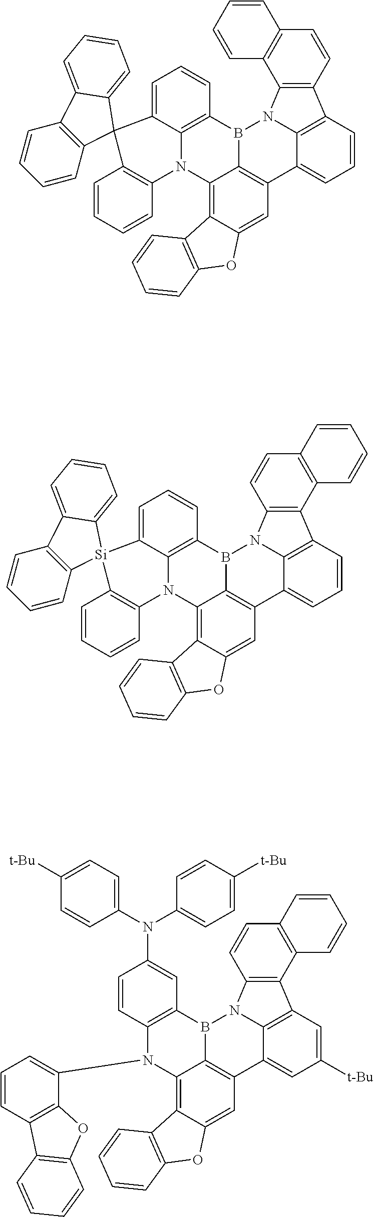 [SMILES: c1ccc2c(c1)-c1ccccc1C21c2ccccc2N2c3c(cccc31)B1c3c(cc4oc5ccccc5c4c32)-c2cccc3c4ccc5ccccc5c4n1c23 ; c1ccc2c(c1)-c1ccccc1[Si]21c2ccccc2N2c3c(cccc31)B1c3c(cc4oc5ccccc5c4c32)-c2cccc3c4c5ccccc5ccc4n1c23 ; CC(C)(C)c1ccc(N(c2ccc(C(C)(C)C)cc2)c2ccc3c(c2)B2c4c(cc5oc6ccccc6c5c4N3c3cccc4c3oc3ccccc34)-c3cc(C(C)(C)C)cc4c5c6ccccc6ccc5n2c34)cc1] 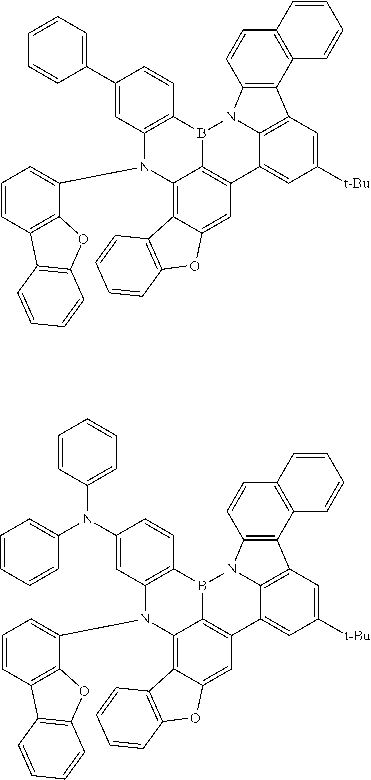 [SMILES: CC(C)(C)c1cc2c3c(c1)c1c4ccccc4ccc1n3B1c3ccc(-c4ccccc4)cc3N(c3cccc4c3oc3ccccc34)c3c1c-2cc1oc2ccccc2c31 ; CC(C)(C)c1cc2c3c(c1)c1c4ccccc4ccc1n3B1c3ccc(N(c4ccccc4)c4ccccc4)cc3N(c3cccc4c3oc3ccccc34)c3c1c-2cc1oc2ccccc2c31] 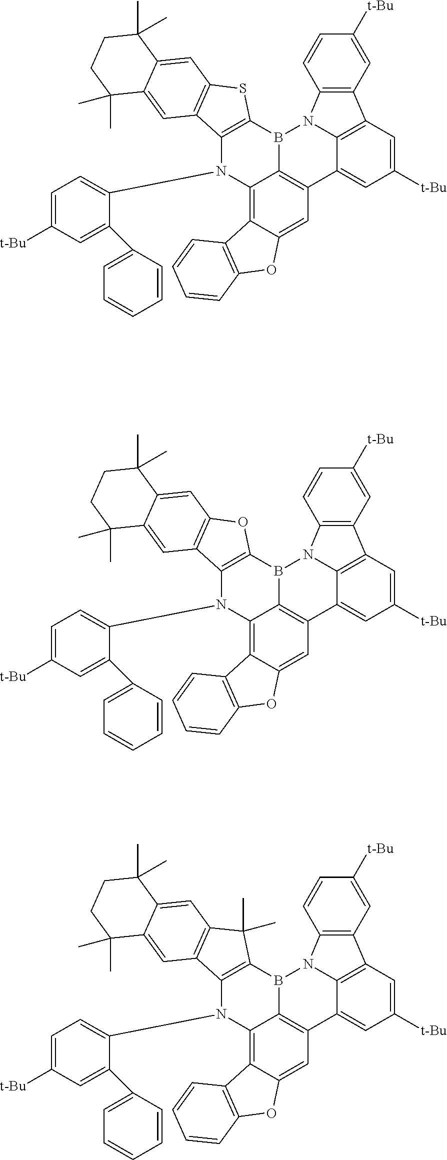 [SMILES: CC(C)(C)c1ccc(N2c3c(sc4cc5c(cc34)C(C)(C)CCC5(C)C)B3c4c(cc5oc6ccccc6c5c42)-c2cc(C(C)(C)C)cc4c5cc(C(C)(C)C)ccc5n3c24)c(-c2ccccc2)c1 ; CC(C)(C)c1ccc(N2c3c(oc4cc5c(cc34)C(C)(C)CCC5(C)C)B3c4c(cc5oc6ccccc6c5c42)-c2cc(C(C)(C)C)cc4c5cc(C(C)(C)C)ccc5n3c24)c(-c2ccccc2)c1 ; CC(C)(C)c1ccc(N2C3=C(B4c5c(cc6oc7ccccc7c6c52)-c2cc(C(C)(C)C)cc5c6cc(C(C)(C)C)ccc6n4c25)C(C)(C)c2cc4c(cc23)C(C)(C)CCC4(C)C)c(-c2ccccc2)c1] 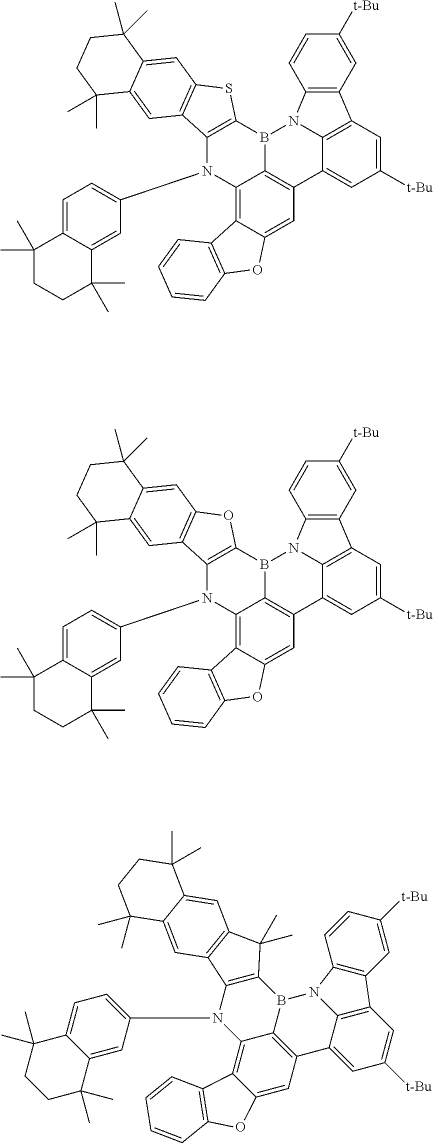 [SMILES: CC(C)(C)c1ccc2c(c1)c1cc(C(C)(C)C)cc3c1n2B1c2sc4cc5c(cc4c2N(c2ccc4c(c2)C(C)(C)CCC4(C)C)c2c1c-3cc1oc3ccccc3c21)C(C)(C)CCC5(C)C ; CC(C)(C)c1ccc2c(c1)c1cc(C(C)(C)C)cc3c1n2B1c2oc4cc5c(cc4c2N(c2ccc4c(c2)C(C)(C)CCC4(C)C)c2c1c-3cc1oc3ccccc3c21)C(C)(C)CCC5(C)C ; CC(C)(C)c1ccc2c(c1)c1cc(C(C)(C)C)cc3c1n2B1C2=C(c4cc5c(cc4C2(C)C)C(C)(C)CCC5(C)C)N(c2ccc4c(c2)C(C)(C)CCC4(C)C)c2c1c-3cc1oc3ccccc3c21] 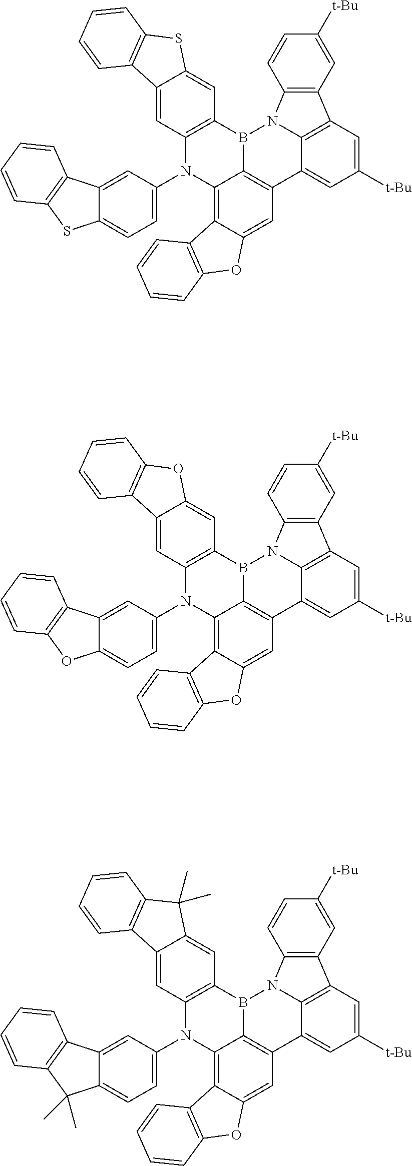 [SMILES: CC(C)(C)c1ccc2c(c1)c1cc(C(C)(C)C)cc3c1n2B1c2cc4sc5ccccc5c4cc2N(c2ccc4sc5ccccc5c4c2)c2c1c-3cc1oc3ccccc3c21 ; CC(C)(C)c1ccc2c(c1)c1cc(C(C)(C)C)cc3c1n2B1c2cc4oc5ccccc5c4cc2N(c2ccc4oc5ccccc5c4c2)c2c1c-3cc1oc3ccccc3c21 ; CC(C)(C)c1ccc2c(c1)c1cc(C(C)(C)C)cc3c1n2B1c2cc4c(cc2N(c2ccc5c(c2)-c2ccccc2C5(C)C)c2c1c-3cc1oc3ccccc3c21)-c1ccccc1C4(C)C] 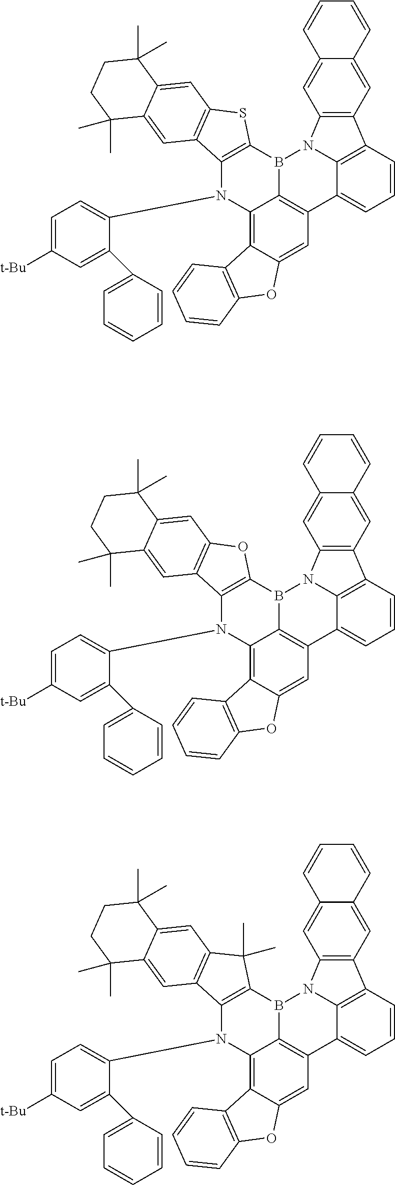 [SMILES: CC(C)(C)c1ccc(N2c3c(sc4cc5c(cc34)C(C)(C)CCC5(C)C)B3c4c(cc5oc6ccccc6c5c42)-c2cccc4c5cc6ccccc6cc5n3c24)c(-c2ccccc2)c1 ; CC(C)(C)c1ccc(N2c3c(oc4cc5c(cc34)C(C)(C)CCC5(C)C)B3c4c(cc5oc6ccccc6c5c42)-c2cccc4c5cc6ccccc6cc5n3c24)c(-c2ccccc2)c1 ; CC(C)(C)c1ccc(N2C3=C(B4c5c(cc6oc7ccccc7c6c52)-c2cccc5c6cc7ccccc7cc6n4c25)C(C)(C)c2cc4c(cc23)C(C)(C)CCC4(C)C)c(-c2ccccc2)c1] 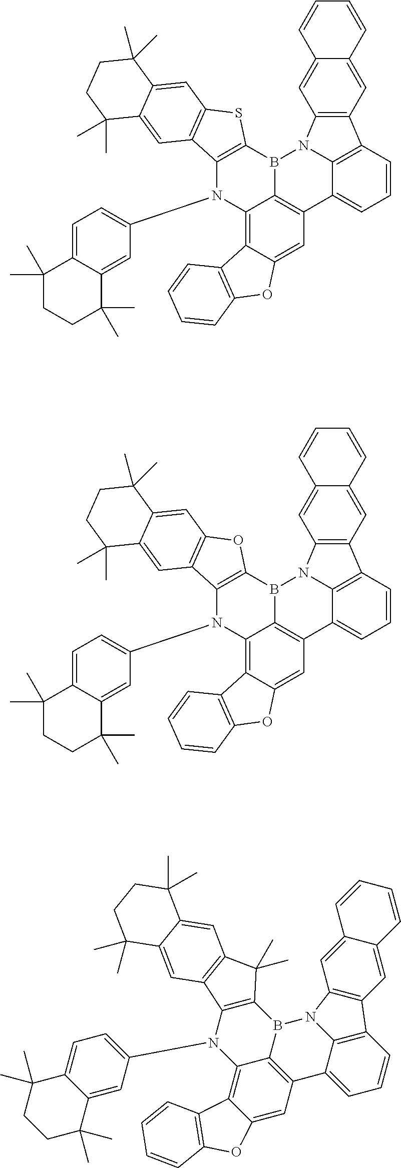 [SMILES: CC1(C)CCC(C)(C)c2cc(N3c4c(sc5cc6c(cc45)C(C)(C)CCC6(C)C)B4c5c(cc6oc7ccccc7c6c53)-c3cccc5c6cc7ccccc7cc6n4c35)ccc21 ; CC1(C)CCC(C)(C)c2cc(N3c4c(oc5cc6c(cc45)C(C)(C)CCC6(C)C)B4c5c(cc6oc7ccccc7c6c53)-c3cccc5c6cc7ccccc7cc6n4c35)ccc21 ; CC1(C)CCC(C)(C)c2cc(N3C4=C(B5c6c(cc7oc8ccccc8c7c63)-c3cccc6c7cc8ccccc8cc7n5c36)C(C)(C)c3cc5c(cc34)C(C)(C)CCC5(C)C)ccc21] 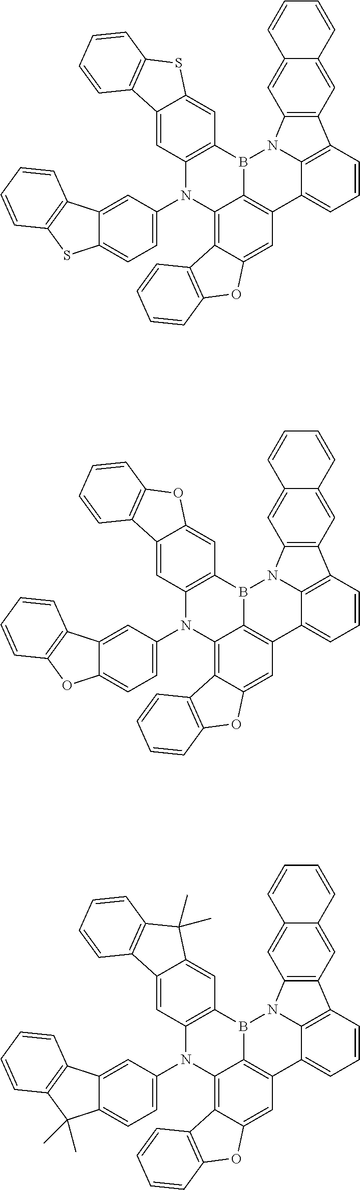 [SMILES: c1ccc2cc3c(cc2c1)c1cccc2c1n3B1c3cc4sc5ccccc5c4cc3N(c3ccc4sc5ccccc5c4c3)c3c1c-2cc1oc2ccccc2c31 ; c1ccc2cc3c(cc2c1)c1cccc2c1n3B1c3cc4oc5ccccc5c4cc3N(c3ccc4oc5ccccc5c4c3)c3c1c-2cc1oc2ccccc2c31 ; CC1(C)c2ccccc2-c2cc(N3c4cc5c(cc4B4c6c(cc7oc8ccccc8c7c63)-c3cccc6c7cc8ccccc8cc7n4c36)C(C)(C)c3ccccc3-5)ccc21] 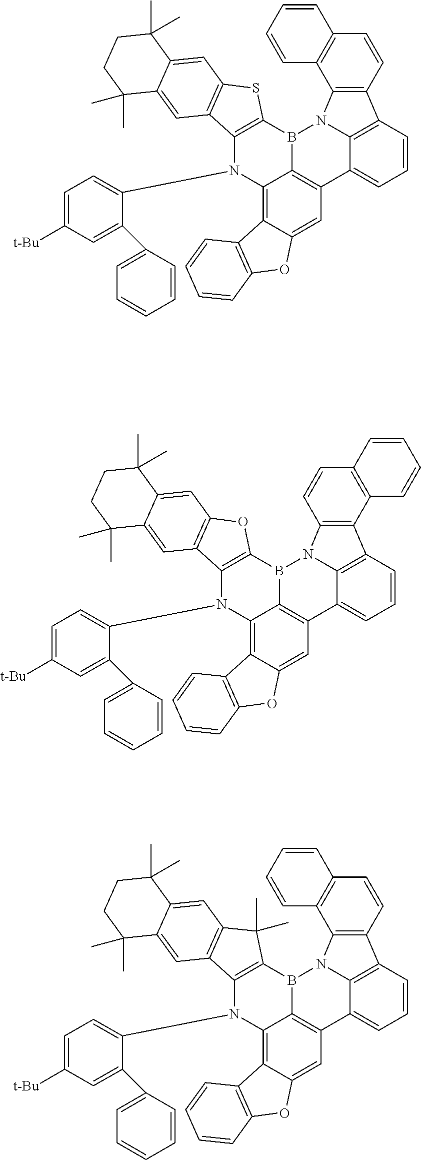 [SMILES: CC(C)(C)c1ccc(N2c3c(sc4cc5c(cc34)C(C)(C)CCC5(C)C)B3c4c(cc5oc6ccccc6c5c42)-c2cccc4c5ccc6ccccc6c5n3c24)c(-c2ccccc2)c1 ; CC(C)(C)c1ccc(N2c3c(oc4cc5c(cc34)C(C)(C)CCC5(C)C)B3c4c(cc5oc6ccccc6c5c42)-c2cccc4c5c6ccccc6ccc5n3c24)c(-c2ccccc2)c1 ; CC(C)(C)c1ccc(N2C3=C(B4c5c(cc6oc7ccccc7c6c52)-c2cccc5c6ccc7ccccc7c6n4c25)C(C)(C)c2cc4c(cc23)C(C)(C)CCC4(C)C)c(-c2ccccc2)c1] 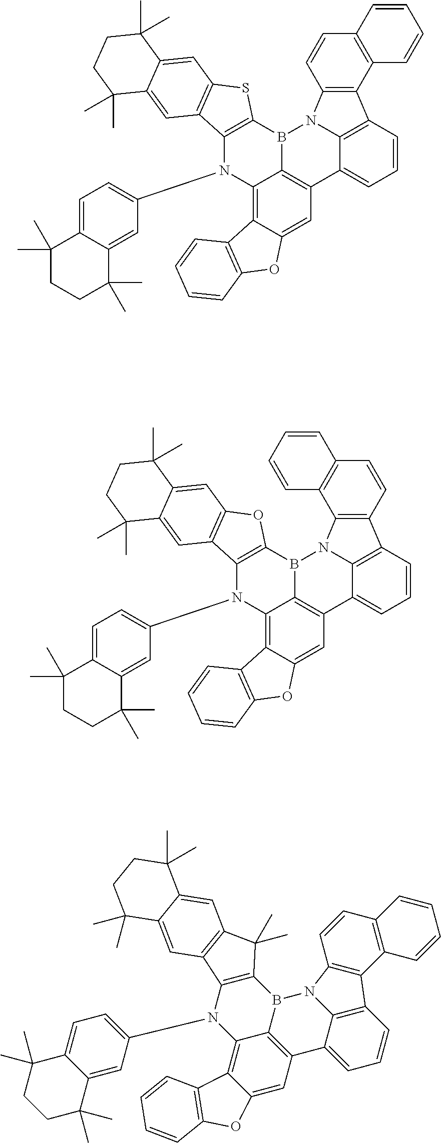 [SMILES: CC1(C)CCC(C)(C)c2cc(N3c4c(sc5cc6c(cc45)C(C)(C)CCC6(C)C)B4c5c(cc6oc7ccccc7c6c53)-c3cccc5c6c7ccccc7ccc6n4c35)ccc21 ; CC1(C)CCC(C)(C)c2cc(N3c4c(oc5cc6c(cc45)C(C)(C)CCC6(C)C)B4c5c(cc6oc7ccccc7c6c53)-c3cccc5c6ccc7ccccc7c6n4c35)ccc21 ; CC1(C)CCC(C)(C)c2cc(N3C4=C(B5c6c(cc7oc8ccccc8c7c63)-c3cccc6c7c8ccccc8ccc7n5c36)C(C)(C)c3cc5c(cc34)C(C)(C)CCC5(C)C)ccc21] 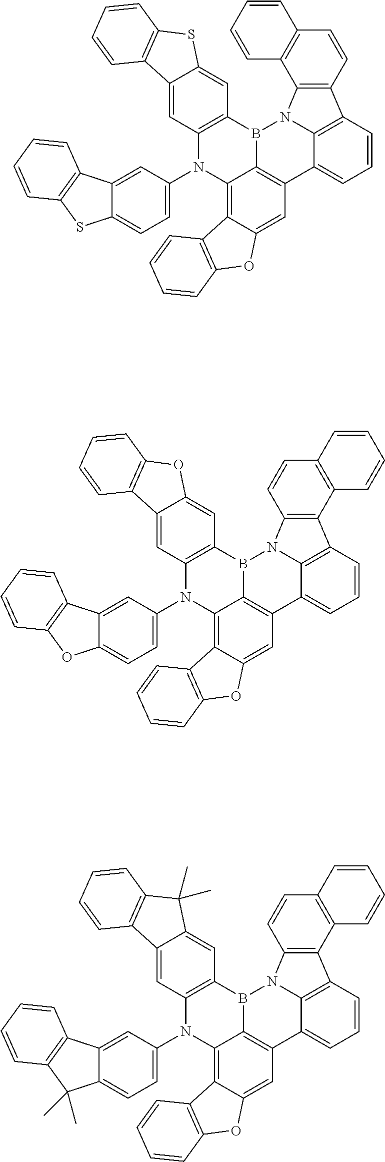 [SMILES: c1ccc2c(c1)ccc1c3cccc4c3n(c21)B1c2cc3sc5ccccc5c3cc2N(c2ccc3sc5ccccc5c3c2)c2c1c-4cc1oc3ccccc3c21 ; c1ccc2c(c1)ccc1c2c2cccc3c2n1B1c2cc4oc5ccccc5c4cc2N(c2ccc4oc5ccccc5c4c2)c2c1c-3cc1oc3ccccc3c21 ; CC1(C)c2ccccc2-c2cc(N3c4cc5c(cc4B4c6c(cc7oc8ccccc8c7c63)-c3cccc6c7c8ccccc8ccc7n4c36)C(C)(C)c3ccccc3-5)ccc21] 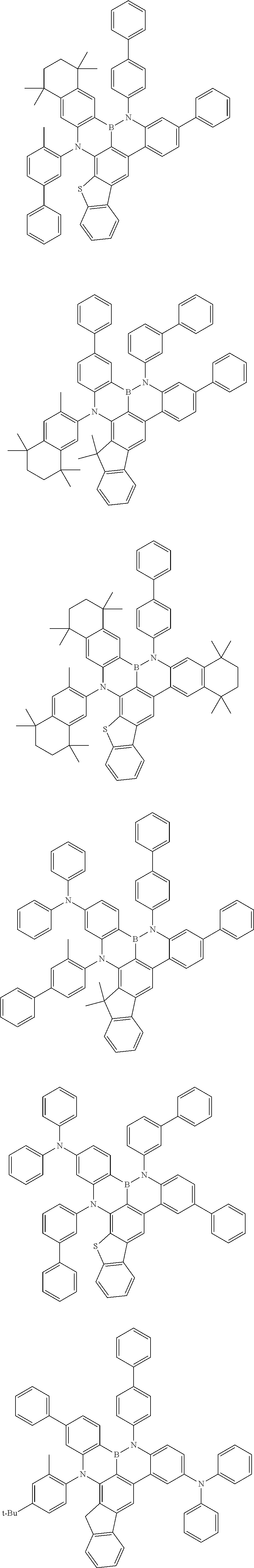 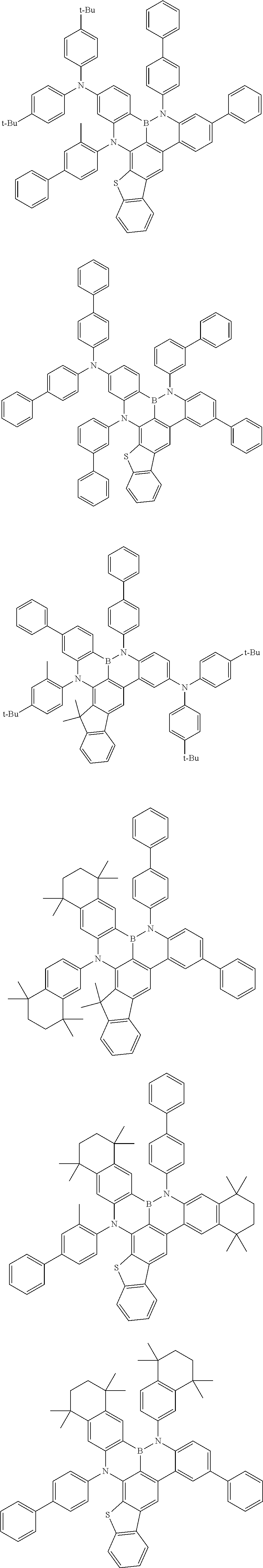 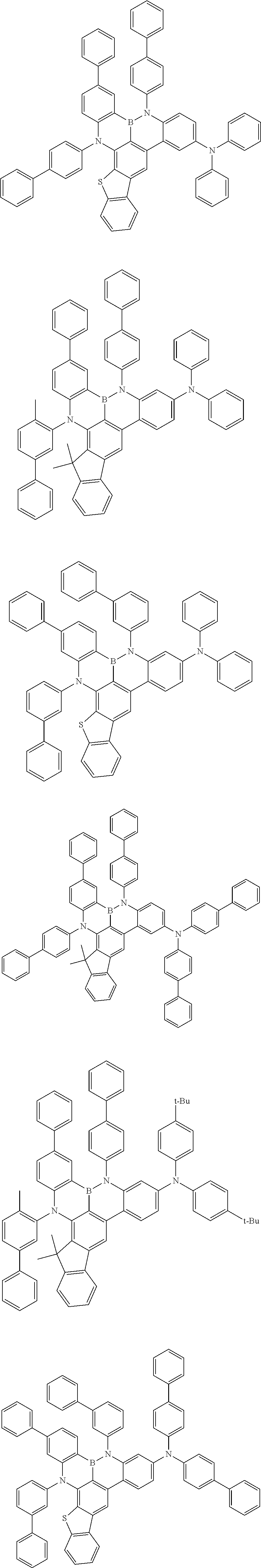 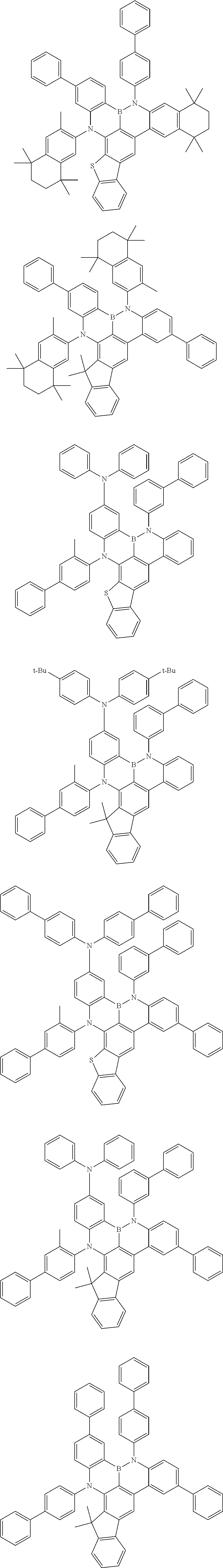 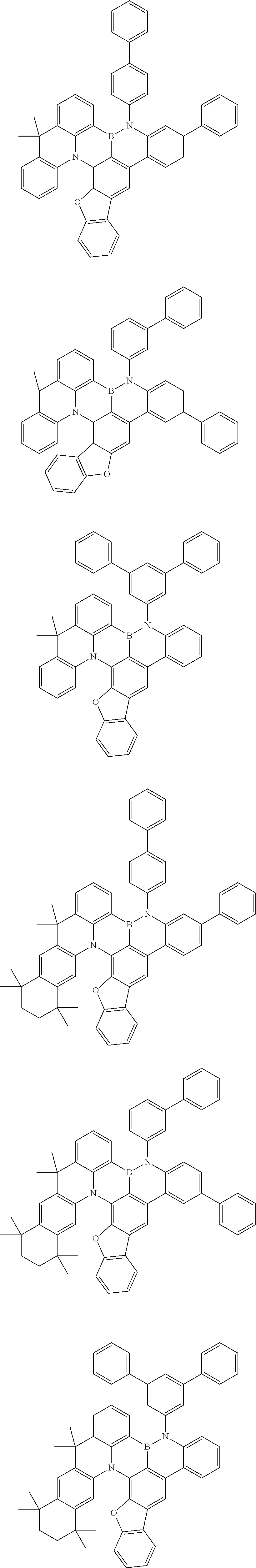 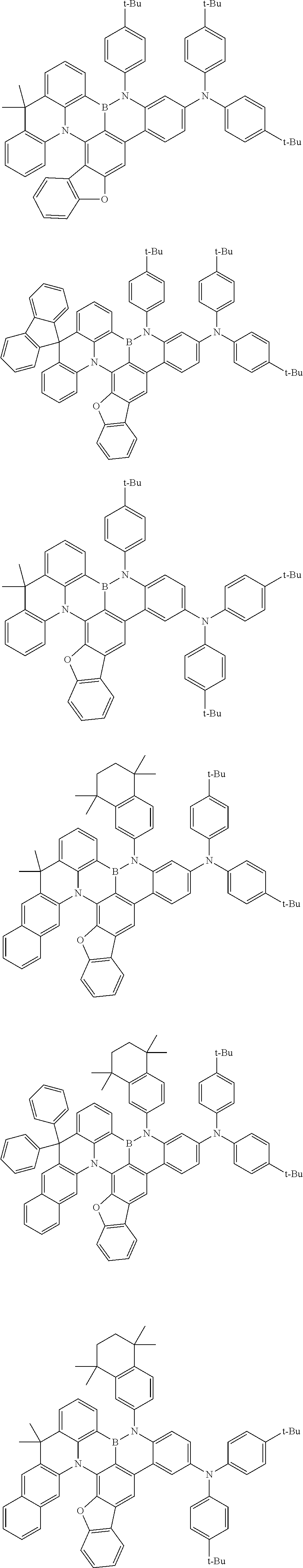 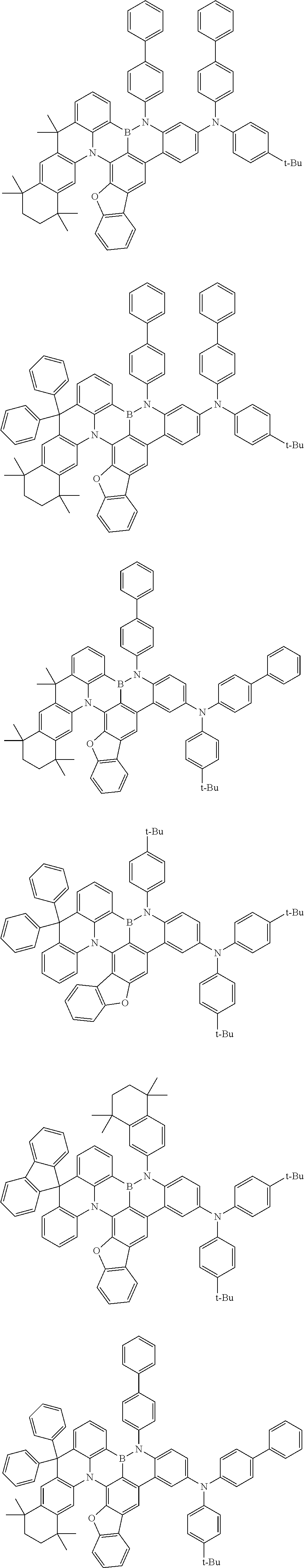 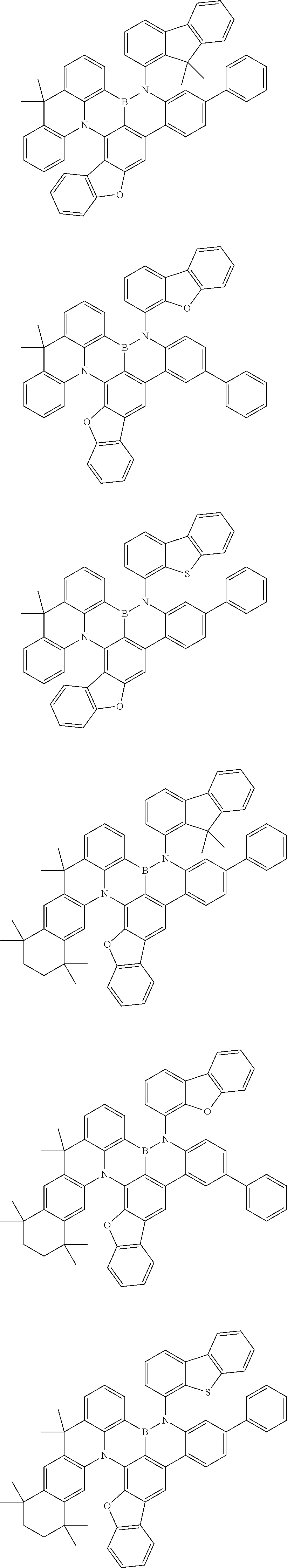 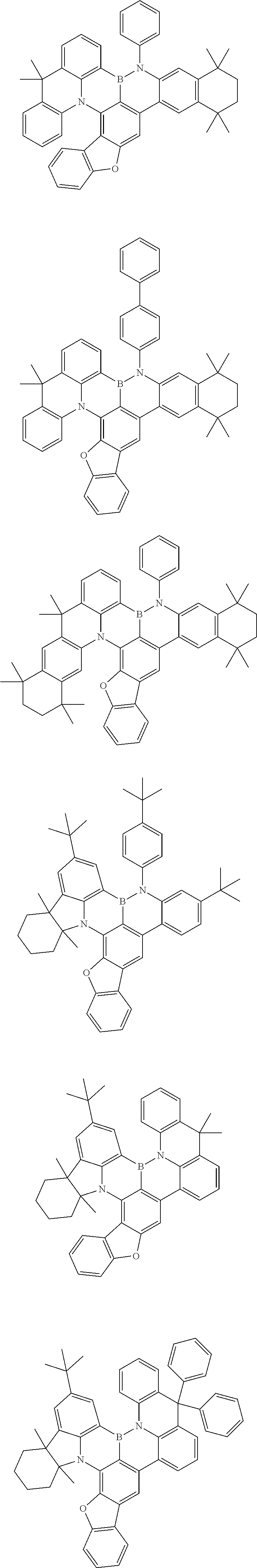 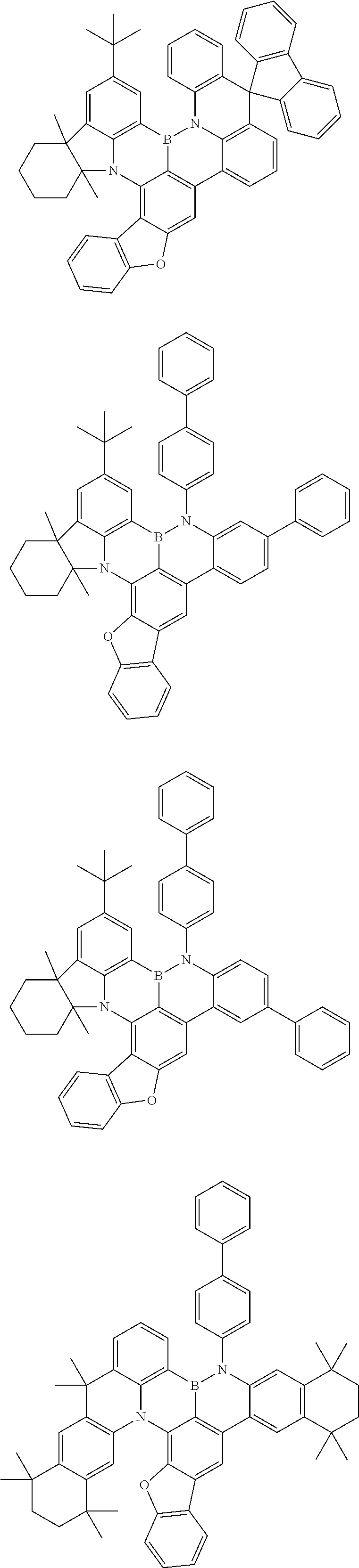 [SMILES: CC(C)(C)c1cc2c3c(c1)C1(C)CCCCC1(C)N3c1c3c(cc4oc5ccccc5c14)-c1cccc4c1N(B23)c1ccccc1C41c2ccccc2-c2ccccc21 ; CC(C)(C)c1cc2c3c(c1)C1(C)CCCCC1(C)N3c1c3c(cc4c1oc1ccccc14)-c1ccc(-c4ccccc4)cc1N(c1ccc(-c4ccccc4)cc1)B23 ; CC(C)(C)c1cc2c3c(c1)C1(C)CCCCC1(C)N3c1c3c(cc4oc5ccccc5c14)-c1cc(-c4ccccc4)ccc1N(c1ccc(-c4ccccc4)cc1)B23 ; CC1(C)CCC(C)(C)c2cc3c(cc21)-c1cc2c(oc4ccccc42)c2c1B(c1cccc4c1N2c1cc2c(cc1C4(C)C)C(C)(C)CCC2(C)C)N3c1ccc(-c2ccccc2)cc1] 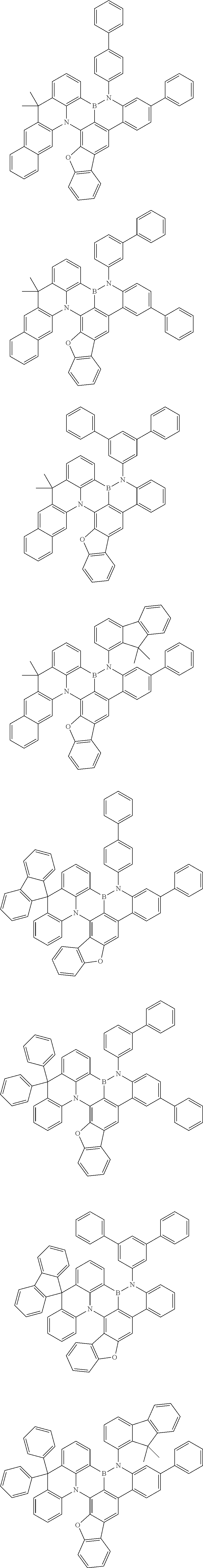 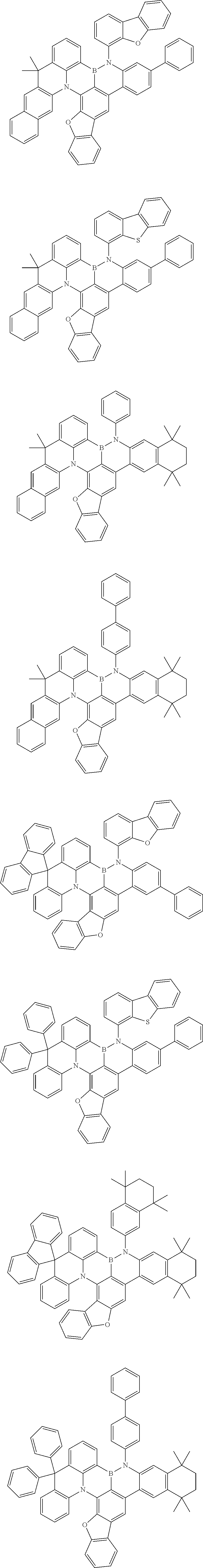 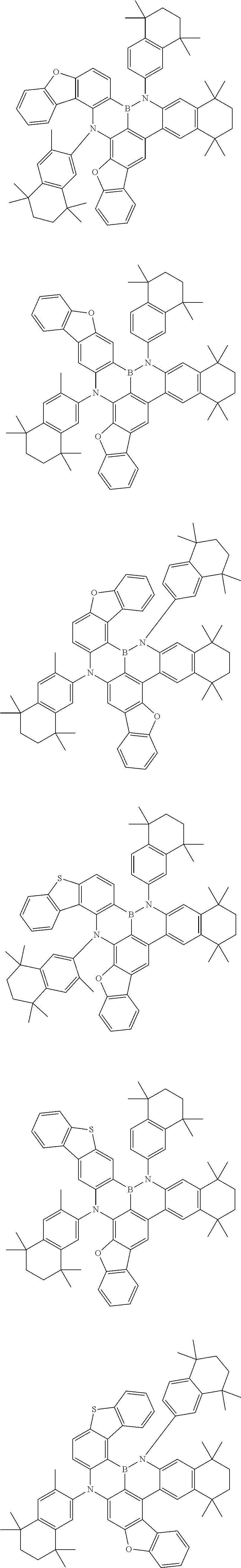 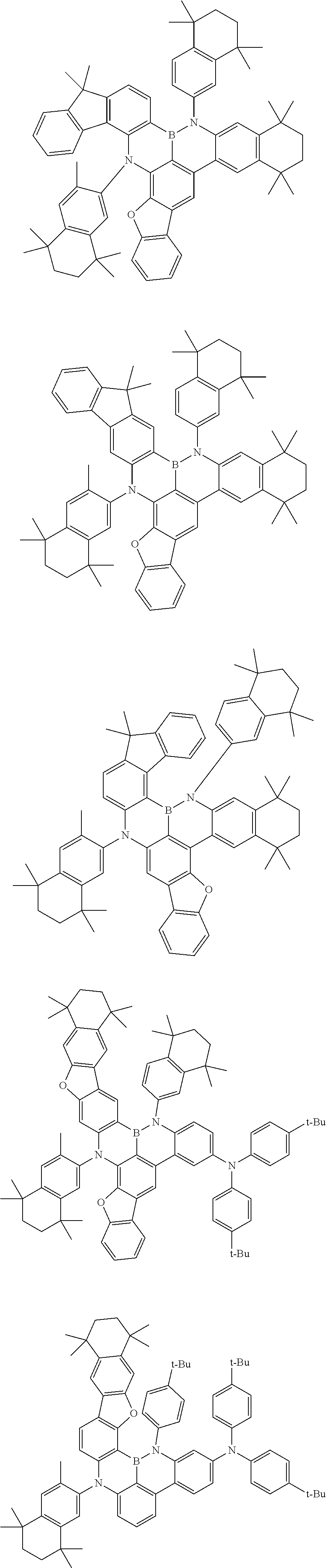 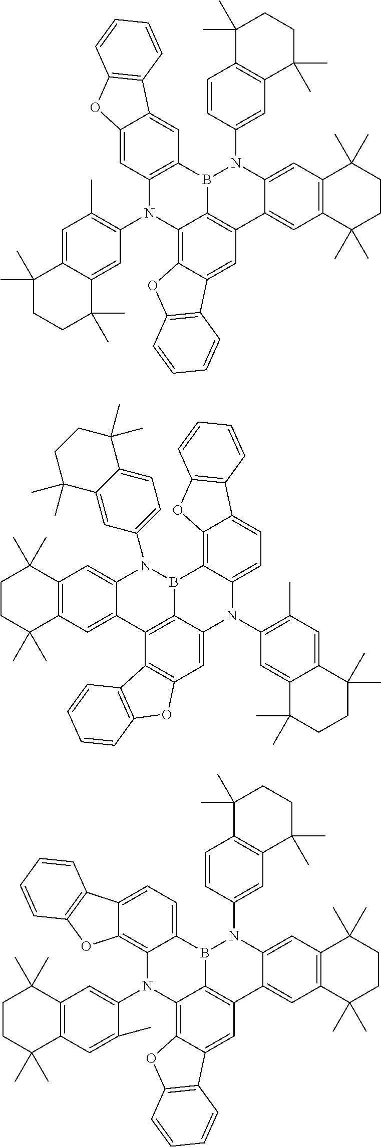 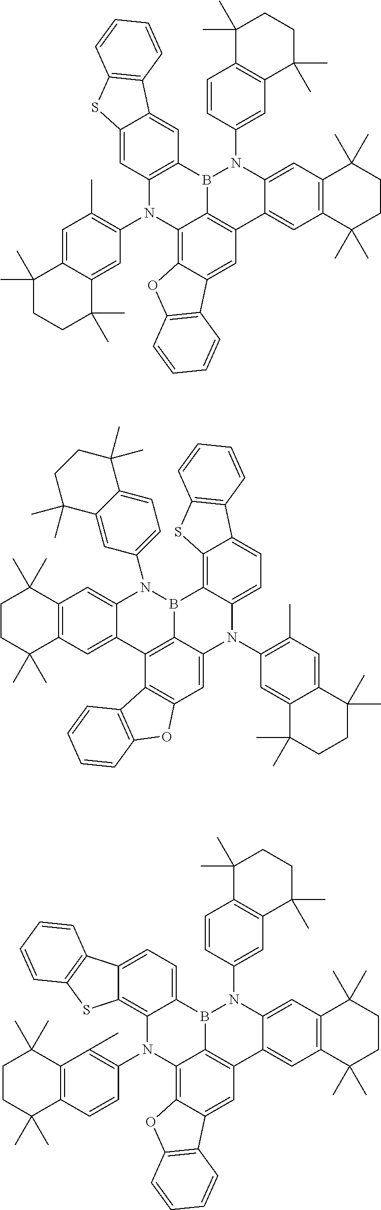 [SMILES: Cc1cc2c(cc1N1c3cc4sc5ccccc5c4cc3B3c4c(cc5c(oc6ccccc65)c41)-c1cc4c(cc1N3c1ccc3c(c1)C(C)(C)CCC3(C)C)C(C)(C)CCC4(C)C)C(C)(C)CCC2(C)C ; Cc1cc2c(cc1N1c3cc4oc5ccccc5c4c4c3B(c3c1ccc1c3sc3ccccc31)N(c1ccc3c(c1)C(C)(C)CCC3(C)C)c1cc3c(cc1-4)C(C)(C)CCC3(C)C)C(C)(C)CCC2(C)C ; Cc1c(N2c3c4c(cc5c3oc3ccccc35)-c3cc5c(cc3N(c3ccc6c(c3)C(C)(C)CCC6(C)C)B4c3ccc4c(sc6ccccc64)c32)C(C)(C)CCC5(C)C)ccc2c1C(C)(C)CCC2(C)C] 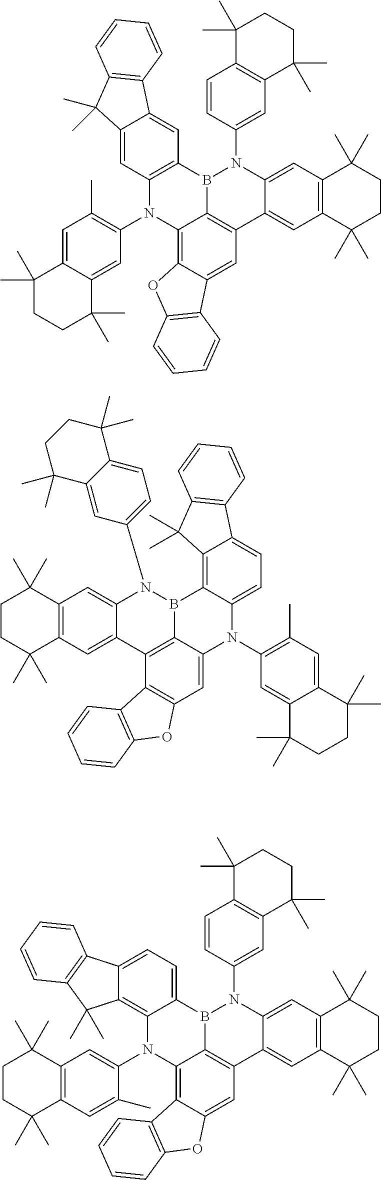 [SMILES: Cc1cc2c(cc1N1c3cc4c(cc3B3c5c(cc6c(oc7ccccc76)c51)-c1cc5c(cc1N3c1ccc3c(c1)C(C)(C)CCC3(C)C)C(C)(C)CCC5(C)C)-c1ccccc1C4(C)C)C(C)(C)CCC2(C)C ; Cc1cc2c(cc1N1c3ccc4c(c3B3c5c1cc1oc6ccccc6c1c5-c1cc5c(cc1N3c1ccc3c(c1)C(C)(C)CCC3(C)C)C(C)(C)CCC5(C)C)C(C)(C)c1ccccc1-4)C(C)(C)CCC2(C)C ; Cc1cc2c(cc1N1c3c(ccc4c3C(C)(C)c3ccccc3-4)B3c4c(cc5oc6ccccc6c5c41)-c1cc4c(cc1N3c1ccc3c(c1)C(C)(C)CCC3(C)C)C(C)(C)CCC4(C)C)C(C)(C)CCC2(C)C] 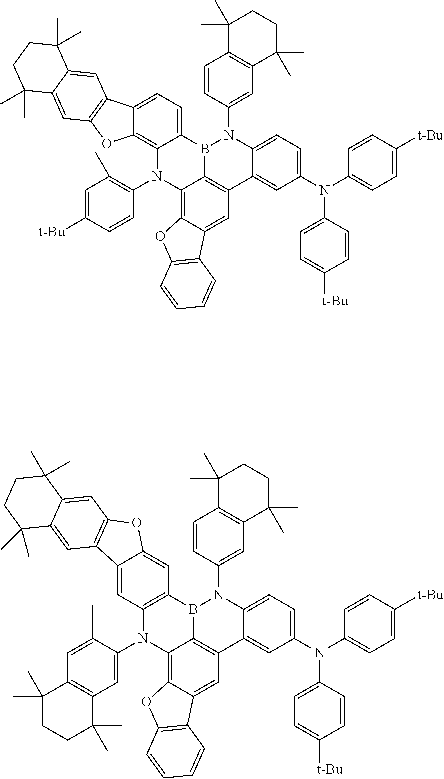 [SMILES: Cc1cc(C(C)(C)C)ccc1N1c2c(ccc3c2oc2cc4c(cc23)C(C)(C)CCC4(C)C)B2c3c(cc4c(oc5ccccc54)c31)-c1cc(N(c3ccc(C(C)(C)C)cc3)c3ccc(C(C)(C)C)cc3)ccc1N2c1ccc2c(c1)C(C)(C)CCC2(C)C ; Cc1cc2c(cc1N1c3cc4c(cc3B3c5c(cc6c(oc7ccccc76)c51)-c1cc(N(c5ccc(C(C)(C)C)cc5)c5ccc(C(C)(C)C)cc5)ccc1N3c1ccc3c(c1)C(C)(C)CCC3(C)C)oc1cc3c(cc14)C(C)(C)CCC3(C)C)C(C)(C)CCC2(C)C] 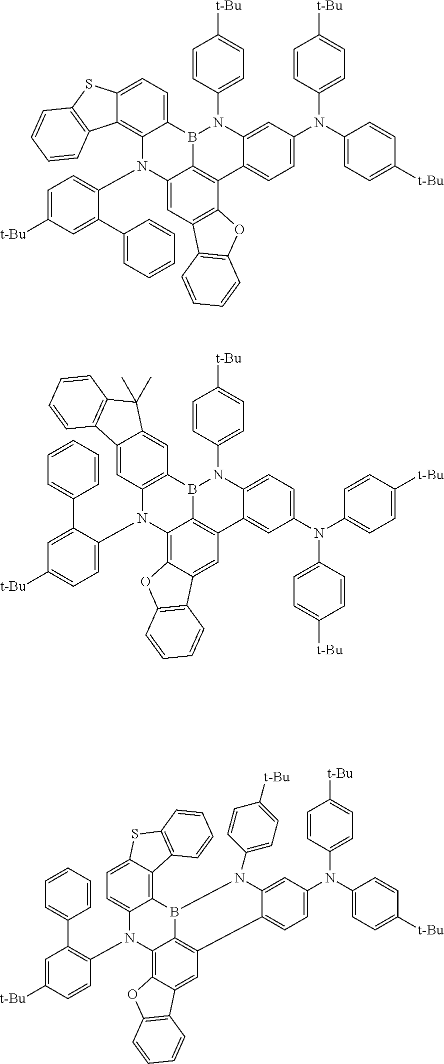 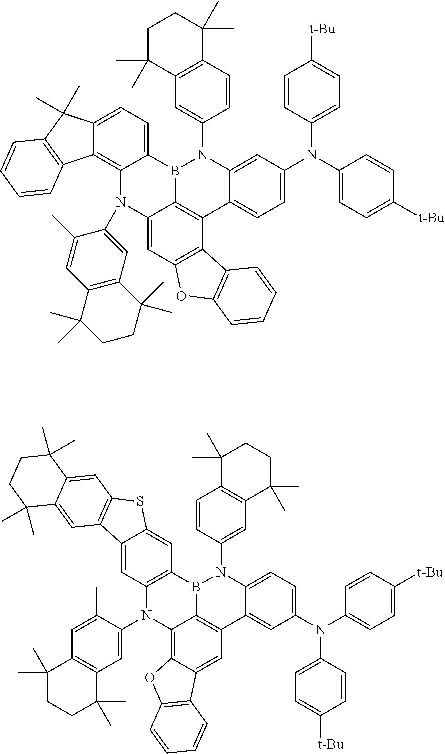 [SMILES: Cc1cc2c(cc1N1c3cc4oc5ccccc5c4c4c3B(c3ccc5c(c31)-c1ccccc1C5(C)C)N(c1ccc3c(c1)C(C)(C)CCC3(C)C)c1cc(N(c3ccc(C(C)(C)C)cc3)c3ccc(C(C)(C)C)cc3)ccc1-4)C(C)(C)CCC2(C)C ; Cc1cc2c(cc1N1c3cc4c(cc3B3c5c(cc6c(oc7ccccc76)c51)-c1cc(N(c5ccc(C(C)(C)C)cc5)c5ccc(C(C)(C)C)cc5)ccc1N3c1ccc3c(c1)C(C)(C)CCC3(C)C)sc1cc3c(cc14)C(C)(C)CCC3(C)C)C(C)(C)CCC2(C)C] 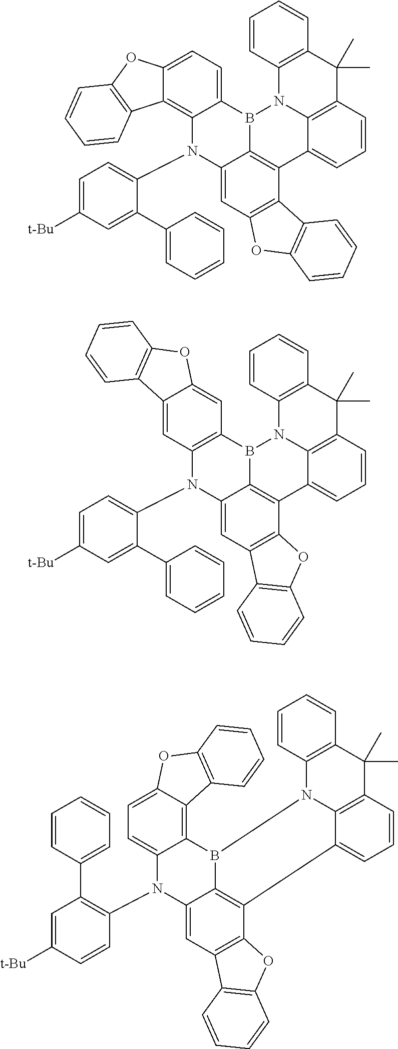 [SMILES: CC(C)(C)c1ccc(N2c3cc4oc5ccccc5c4c4c3B(c3ccc5oc6ccccc6c5c32)N2c3ccccc3C(C)(C)c3cccc-4c32)c(-c2ccccc2)c1 ; CC(C)(C)c1ccc(N2c3cc4c(cc3B3c5c2cc2c(oc6ccccc62)c5-c2cccc5c2N3c2ccccc2C5(C)C)oc2ccccc24)c(-c2ccccc2)c1 ; CC(C)(C)c1ccc(N2c3cc4c(oc5ccccc54)c4c3B(c3c2ccc2oc5ccccc5c32)N2c3ccccc3C(C)(C)c3cccc-4c32)c(-c2ccccc2)c1] 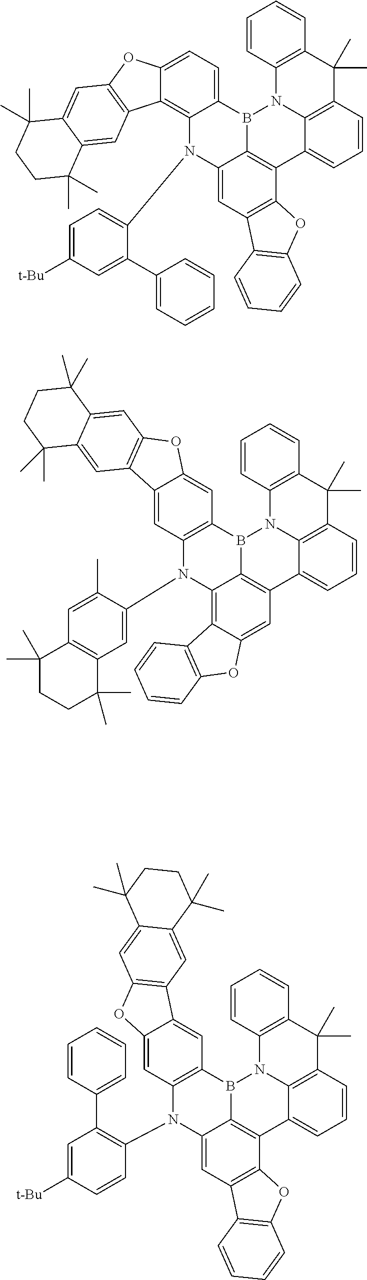 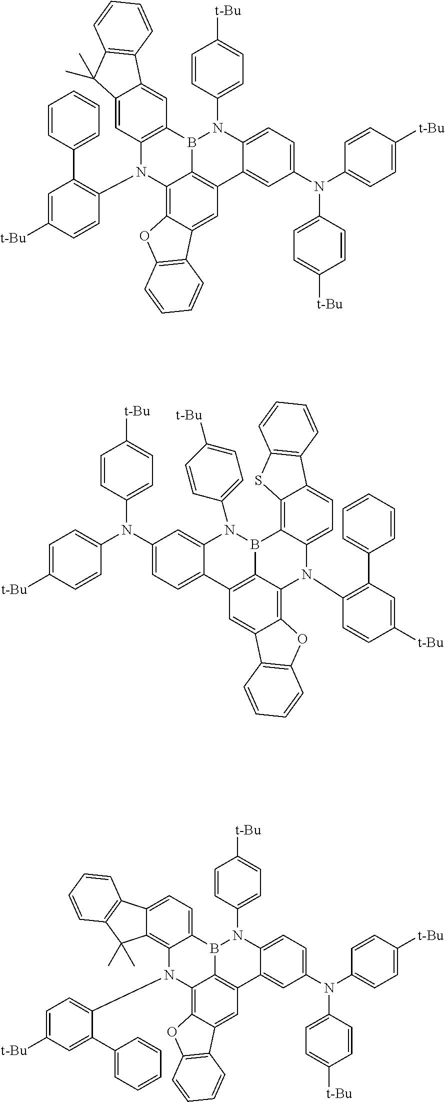 [SMILES: CC(C)(C)c1ccc(N2B3c4cc5c(cc4N(c4ccc(C(C)(C)C)cc4-c4ccccc4)c4c3c(cc3c4oc4ccccc43)-c3cc(N(c4ccc(C(C)(C)C)cc4)c4ccc(C(C)(C)C)cc4)ccc32)C(C)(C)c2ccccc2-5)cc1 ; CC(C)(C)c1ccc(N2B3c4c(cc5c(oc6ccccc65)c4N(c4ccc(C(C)(C)C)cc4-c4ccccc4)c4ccc5c(sc6ccccc65)c43)-c3ccc(N(c4ccc(C(C)(C)C)cc4)c4ccc(C(C)(C)C)cc4)cc32)cc1 ; CC(C)(C)c1ccc(N2B3c4ccc5c(c4N(c4ccc(C(C)(C)C)cc4-c4ccccc4)c4c3c(cc3c4oc4ccccc43)-c3cc(N(c4ccc(C(C)(C)C)cc4)c4ccc(C(C)(C)C)cc4)ccc32)C(C)(C)c2ccccc2-5)cc1] 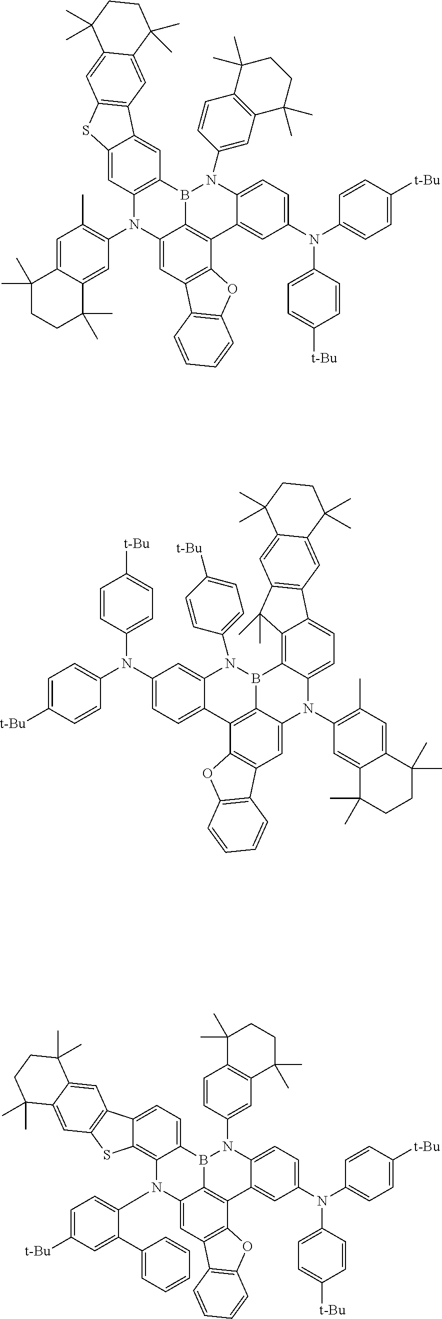 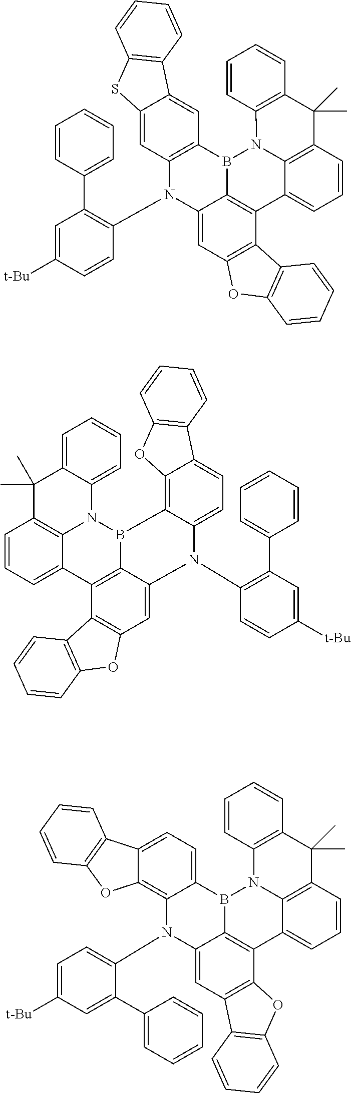 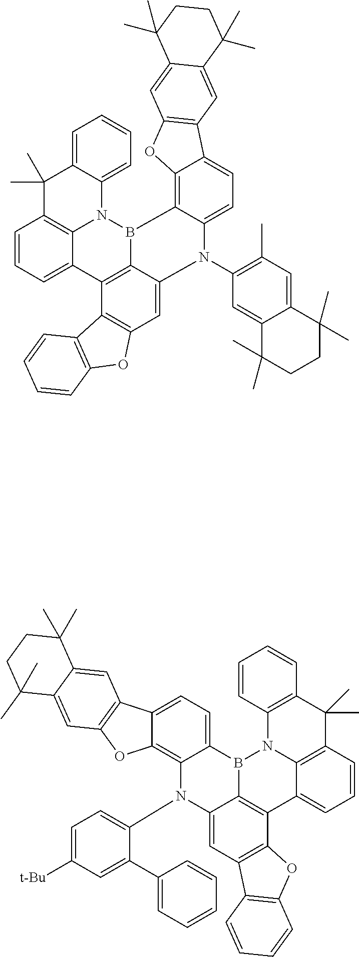 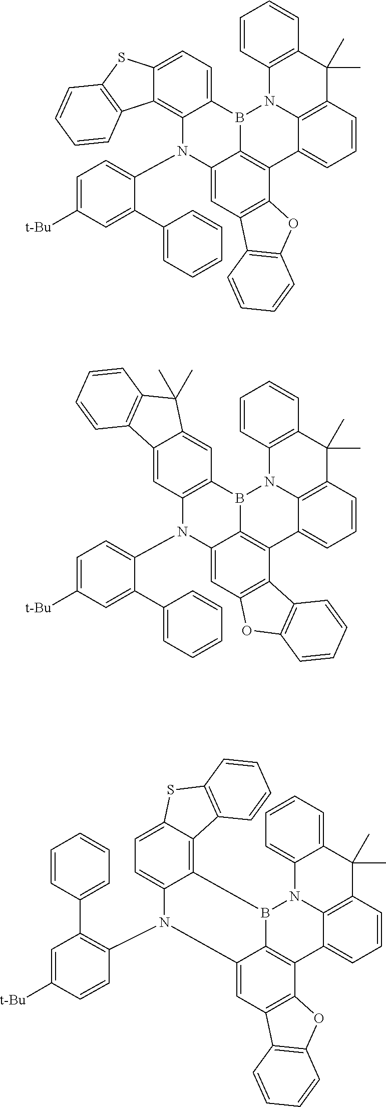 [SMILES: CC(C)(C)c1ccc(N2c3cc4c(oc5ccccc54)c4c3B(c3ccc5sc6ccccc6c5c32)N2c3ccccc3C(C)(C)c3cccc-4c32)c(-c2ccccc2)c1 ; CC(C)(C)c1ccc(N2c3cc4c(cc3B3c5c2cc2oc6ccccc6c2c5-c2cccc5c2N3c2ccccc2C5(C)C)C(C)(C)c2ccccc2-4)c(-c2ccccc2)c1 ; CC(C)(C)c1ccc(N2c3cc4c(oc5ccccc54)c4c3B(c3c2ccc2sc5ccccc5c32)N2c3ccccc3C(C)(C)c3cccc-4c32)c(-c2ccccc2)c1] 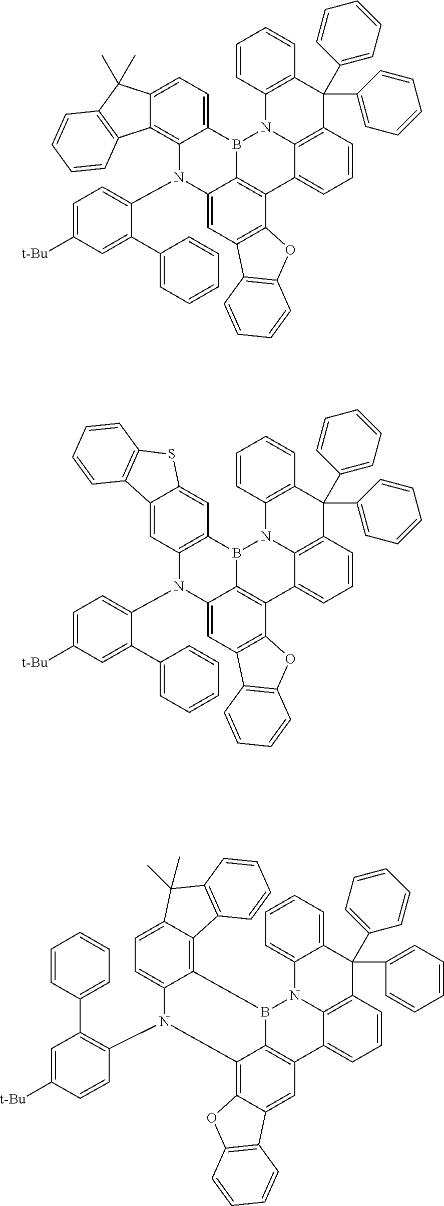 [SMILES: CC(C)(C)c1ccc(N2c3cc4c(oc5ccccc54)c4c3B(c3ccc5c(c32)-c2ccccc2C5(C)C)N2c3ccccc3C(c3ccccc3)(c3ccccc3)c3cccc-4c32)c(-c2ccccc2)c1 ; CC(C)(C)c1ccc(N2c3cc4c(cc3B3c5c2cc2c(oc6ccccc62)c5-c2cccc5c2N3c2ccccc2C5(c2ccccc2)c2ccccc2)sc2ccccc24)c(-c2ccccc2)c1 ; CC(C)(C)c1ccc(N2c3ccc4c(c3B3c5c(cc6c(oc7ccccc76)c52)-c2cccc5c2N3c2ccccc2C5(c2ccccc2)c2ccccc2)-c2ccccc2C4(C)C)c(-c2ccccc2)c1] 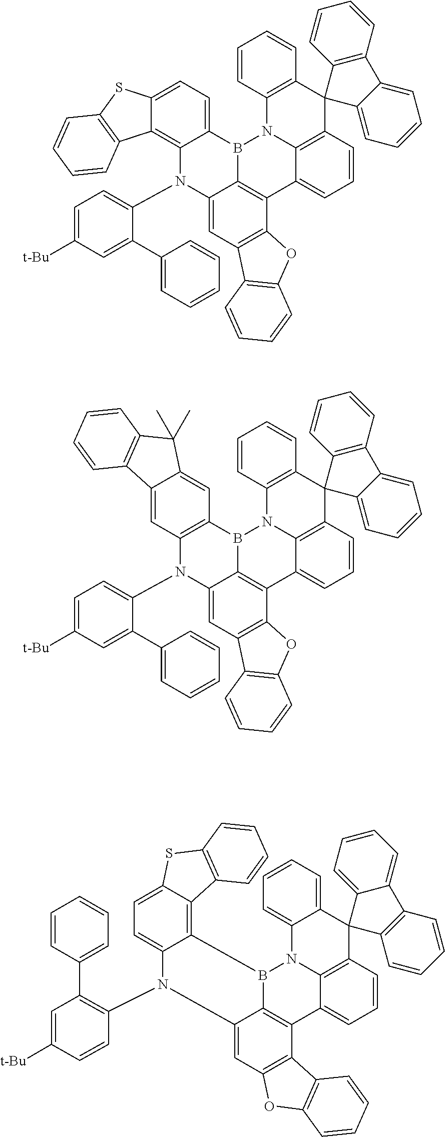 [SMILES: CC(C)(C)c1ccc(N2c3cc4c(oc5ccccc54)c4c3B(c3ccc5sc6ccccc6c5c32)N2c3ccccc3C3(c5ccccc5-c5ccccc53)c3cccc-4c32)c(-c2ccccc2)c1 ; CC(C)(C)c1ccc(N2c3cc4c(cc3B3c5c2cc2c(oc6ccccc62)c5-c2cccc5c2N3c2ccccc2C52c3ccccc3-c3ccccc32)C(C)(C)c2ccccc2-4)c(-c2ccccc2)c1 ; CC(C)(C)c1ccc(N2c3cc4oc5ccccc5c4c4c3B(c3c2ccc2sc5ccccc5c32)N2c3ccccc3C3(c5ccccc5-c5ccccc53)c3cccc-4c32)c(-c2ccccc2)c1] 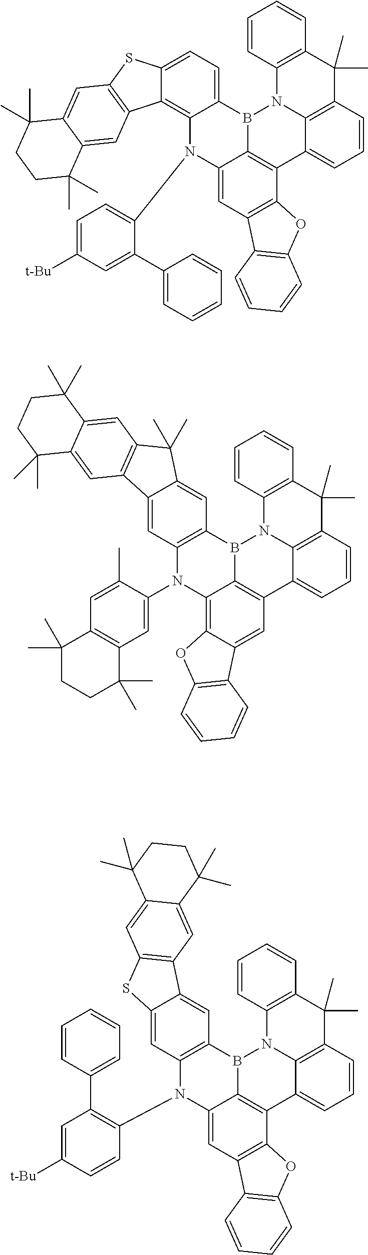 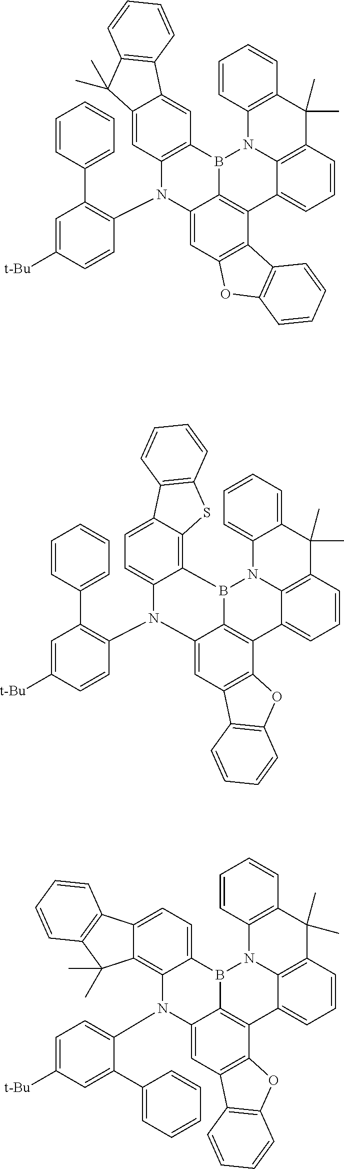 [SMILES: CC(C)(C)c1ccc(N2c3cc4c(cc3B3c5c2cc2oc6ccccc6c2c5-c2cccc5c2N3c2ccccc2C5(C)C)-c2ccccc2C4(C)C)c(-c2ccccc2)c1 ; CC(C)(C)c1ccc(N2c3cc4c(oc5ccccc54)c4c3B(c3c2ccc2c3sc3ccccc32)N2c3ccccc3C(C)(C)c3cccc-4c32)c(-c2ccccc2)c1 ; CC(C)(C)c1ccc(N2c3cc4c(oc5ccccc54)c4c3B(c3ccc5c(c32)C(C)(C)c2ccccc2-5)N2c3ccccc3C(C)(C)c3cccc-4c32)c(-c2ccccc2)c1] 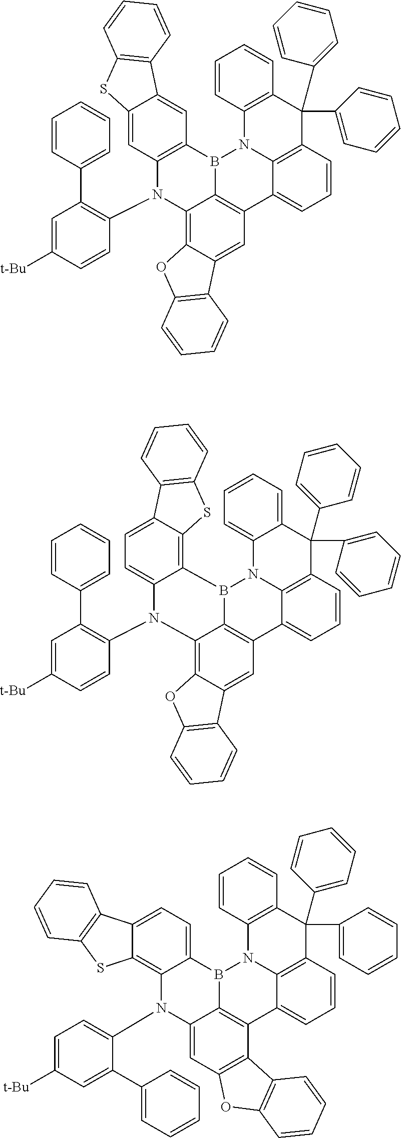 [SMILES: CC(C)(C)c1ccc(N2c3cc4sc5ccccc5c4cc3B3c4c(cc5c(oc6ccccc65)c42)-c2cccc4c2N3c2ccccc2C4(c2ccccc2)c2ccccc2)c(-c2ccccc2)c1 ; CC(C)(C)c1ccc(N2c3ccc4c(sc5ccccc54)c3B3c4c(cc5c(oc6ccccc65)c42)-c2cccc4c2N3c2ccccc2C4(c2ccccc2)c2ccccc2)c(-c2ccccc2)c1 ; CC(C)(C)c1ccc(N2c3cc4oc5ccccc5c4c4c3B(c3ccc5c(sc6ccccc65)c32)N2c3ccccc3C(c3ccccc3)(c3ccccc3)c3cccc-4c32)c(-c2ccccc2)c1] 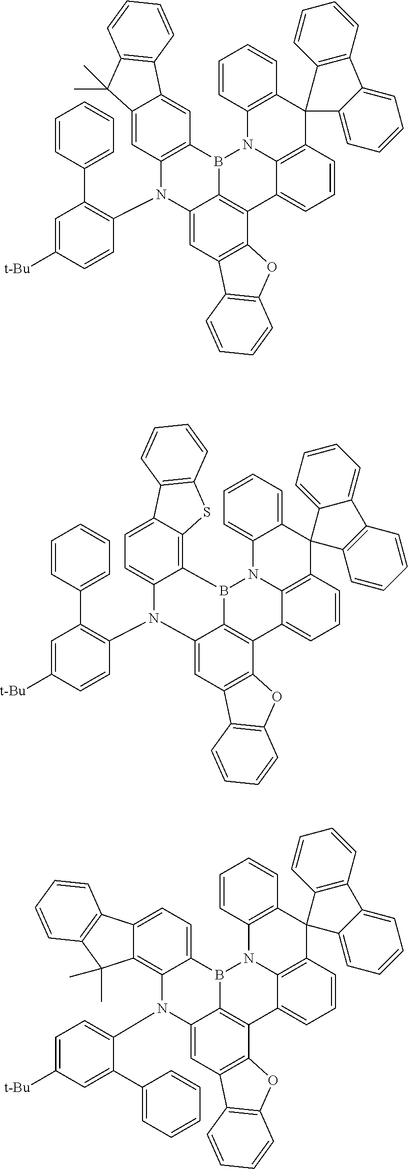 [SMILES: CC(C)(C)c1ccc(N2c3cc4c(cc3B3c5c2cc2c(oc6ccccc62)c5-c2cccc5c2N3c2ccccc2C52c3ccccc3-c3ccccc32)-c2ccccc2C4(C)C)c(-c2ccccc2)c1 ; CC(C)(C)c1ccc(N2c3cc4c(oc5ccccc54)c4c3B(c3c2ccc2c3sc3ccccc32)N2c3ccccc3C3(c5ccccc5-c5ccccc53)c3cccc-4c32)c(-c2ccccc2)c1 ; CC(C)(C)c1ccc(N2c3cc4c(oc5ccccc54)c4c3B(c3ccc5c(c32)C(C)(C)c2ccccc2-5)N2c3ccccc3C3(c5ccccc5-c5ccccc53)c3cccc-4c32)c(-c2ccccc2)c1] 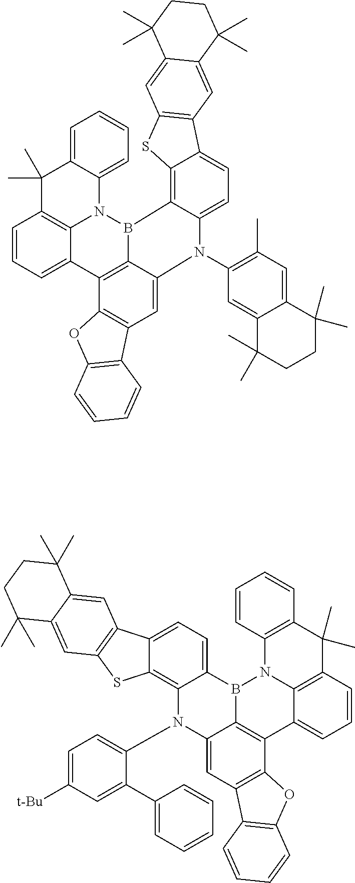 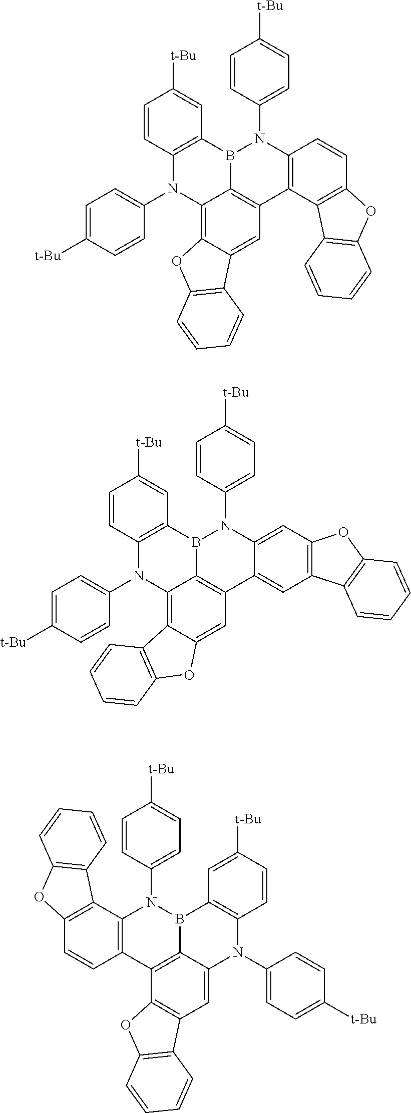 [SMILES: CC(C)(C)c1ccc(N2B3c4cc(C(C)(C)C)ccc4N(c4ccc(C(C)(C)C)cc4)c4c3c(cc3c4oc4ccccc43)-c3c2ccc2oc4ccccc4c32)cc1 ; CC(C)(C)c1ccc(N2B3c4cc(C(C)(C)C)ccc4N(c4ccc(C(C)(C)C)cc4)c4c3c(cc3oc5ccccc5c43)-c3cc4c(cc32)oc2ccccc24)cc1 ; CC(C)(C)c1ccc(N2B3c4cc(C(C)(C)C)ccc4N(c4ccc(C(C)(C)C)cc4)c4cc5c(oc6ccccc65)c(c43)-c3ccc4oc5ccccc5c4c32)cc1] 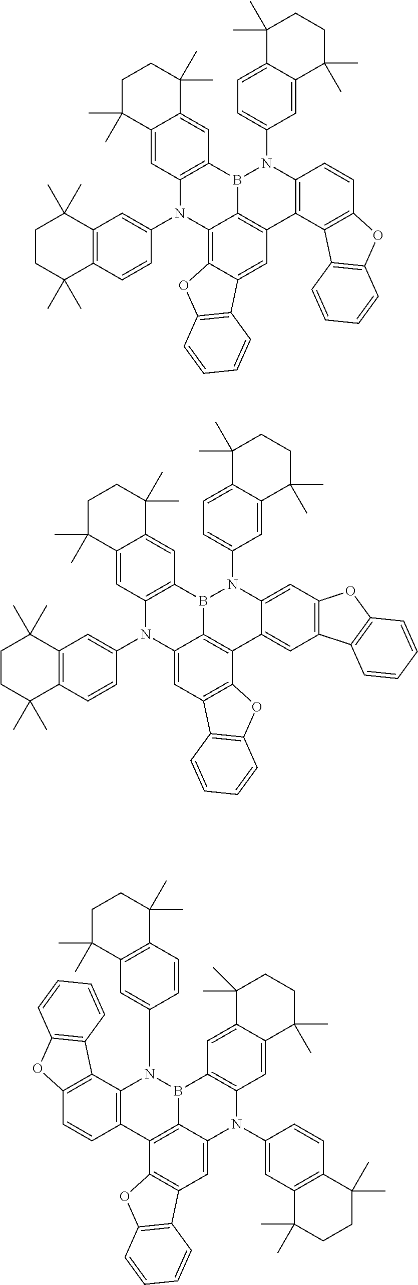 [SMILES: CC1(C)CCC(C)(C)c2cc(N3B4c5cc6c(cc5N(c5ccc7c(c5)C(C)(C)CCC7(C)C)c5c4c(cc4c5oc5ccccc54)-c4c3ccc3oc5ccccc5c43)C(C)(C)CCC6(C)C)ccc21 ; CC1(C)CCC(C)(C)c2cc(N3B4c5cc6c(cc5N(c5ccc7c(c5)C(C)(C)CCC7(C)C)c5cc7c(oc8ccccc87)c(c54)-c4cc5c(cc43)oc3ccccc35)C(C)(C)CCC6(C)C)ccc21 ; CC1(C)CCC(C)(C)c2cc(N3B4c5cc6c(cc5N(c5ccc7c(c5)C(C)(C)CCC7(C)C)c5cc7c(oc8ccccc87)c(c54)-c4ccc5oc7ccccc7c5c43)C(C)(C)CCC6(C)C)ccc21] 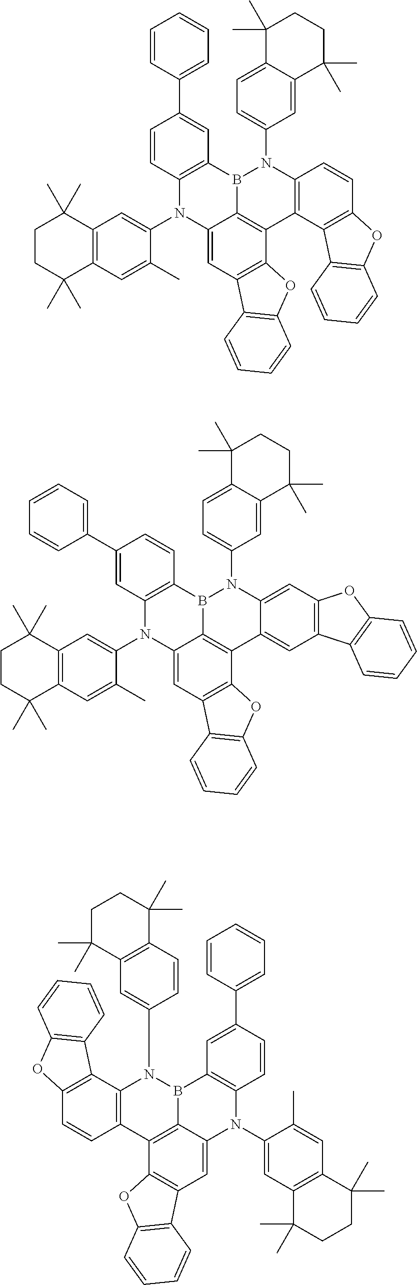 [SMILES: Cc1cc2c(cc1N1c3ccc(-c4ccccc4)cc3B3c4c1cc1c(oc5ccccc51)c4-c1c(ccc4oc5ccccc5c14)N3c1ccc3c(c1)C(C)(C)CCC3(C)C)C(C)(C)CCC2(C)C ; Cc1cc2c(cc1N1c3cc(-c4ccccc4)ccc3B3c4c1cc1c(oc5ccccc51)c4-c1cc4c(cc1N3c1ccc3c(c1)C(C)(C)CCC3(C)C)oc1ccccc14)C(C)(C)CCC2(C)C ; Cc1cc2c(cc1N1c3ccc(-c4ccccc4)cc3B3c4c1cc1c(oc5ccccc51)c4-c1ccc4oc5ccccc5c4c1N3c1ccc3c(c1)C(C)(C)CCC3(C)C)C(C)(C)CCC2(C)C] 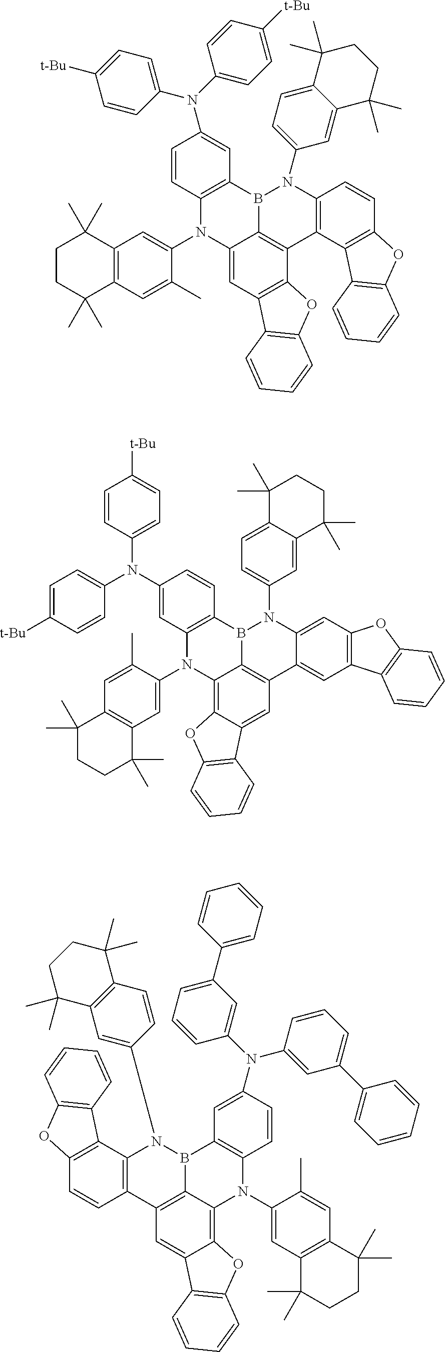 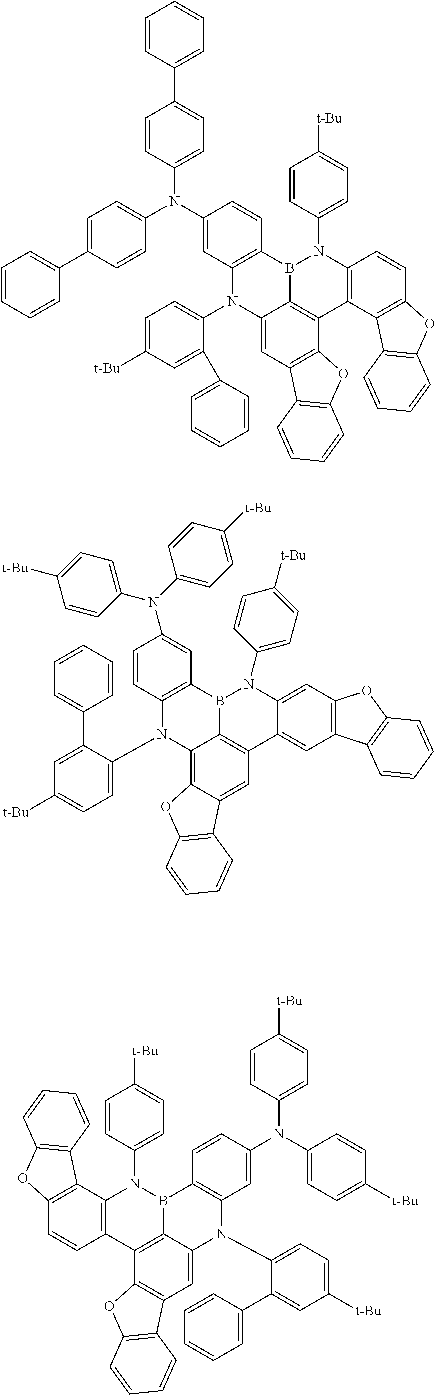 [SMILES: CC(C)(C)c1ccc(N2B3c4ccc(N(c5ccc(-c6ccccc6)cc5)c5ccc(-c6ccccc6)cc5)cc4N(c4ccc(C(C)(C)C)cc4-c4ccccc4)c4cc5c(oc6ccccc65)c(c43)-c3c2ccc2oc4ccccc4c32)cc1 ; CC(C)(C)c1ccc(N2B3c4cc(N(c5ccc(C(C)(C)C)cc5)c5ccc(C(C)(C)C)cc5)ccc4N(c4ccc(C(C)(C)C)cc4-c4ccccc4)c4c3c(cc3c4oc4ccccc43)-c3cc4c(cc32)oc2ccccc24)cc1 ; CC(C)(C)c1ccc(N2B3c4ccc(N(c5ccc(C(C)(C)C)cc5)c5ccc(C(C)(C)C)cc5)cc4N(c4ccc(C(C)(C)C)cc4-c4ccccc4)c4cc5c(oc6ccccc65)c(c43)-c3ccc4oc5ccccc5c4c32)cc1] 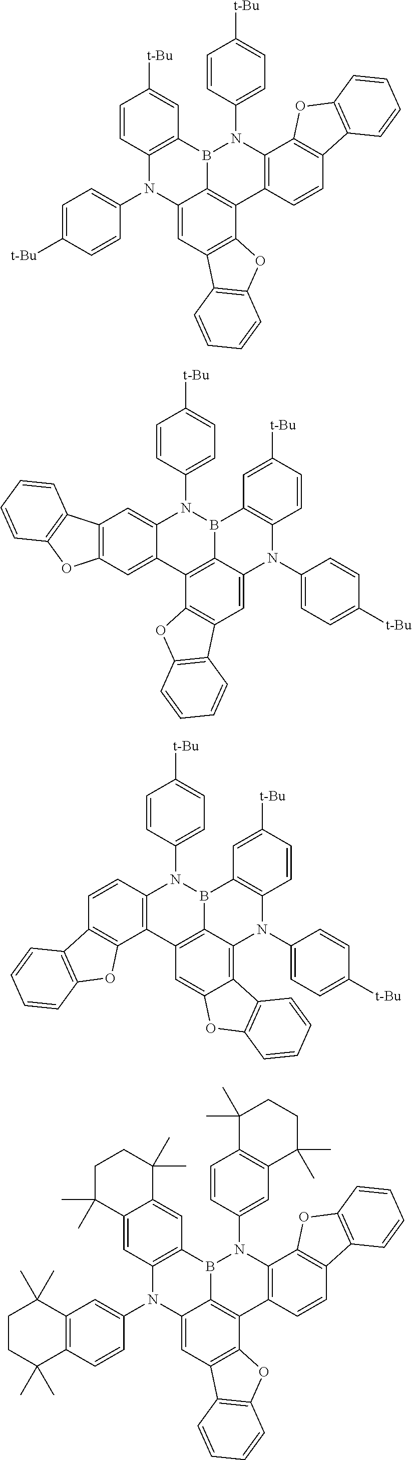 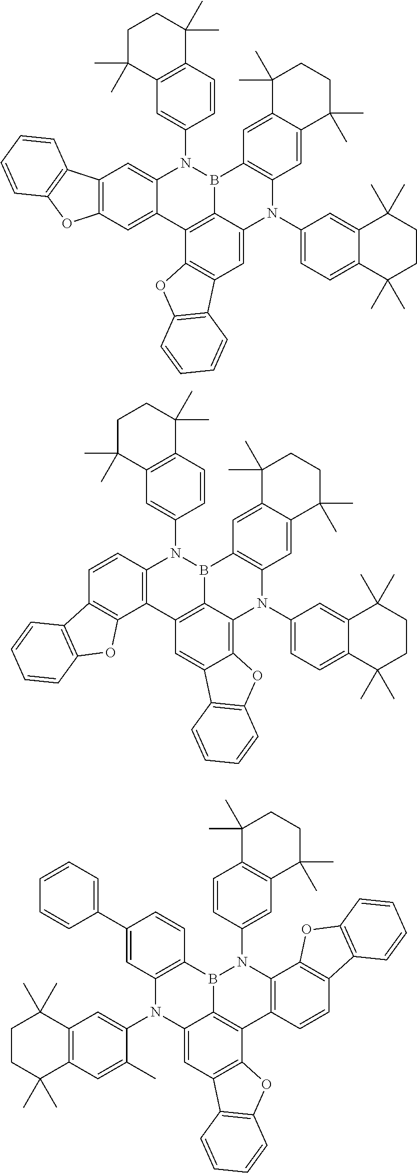 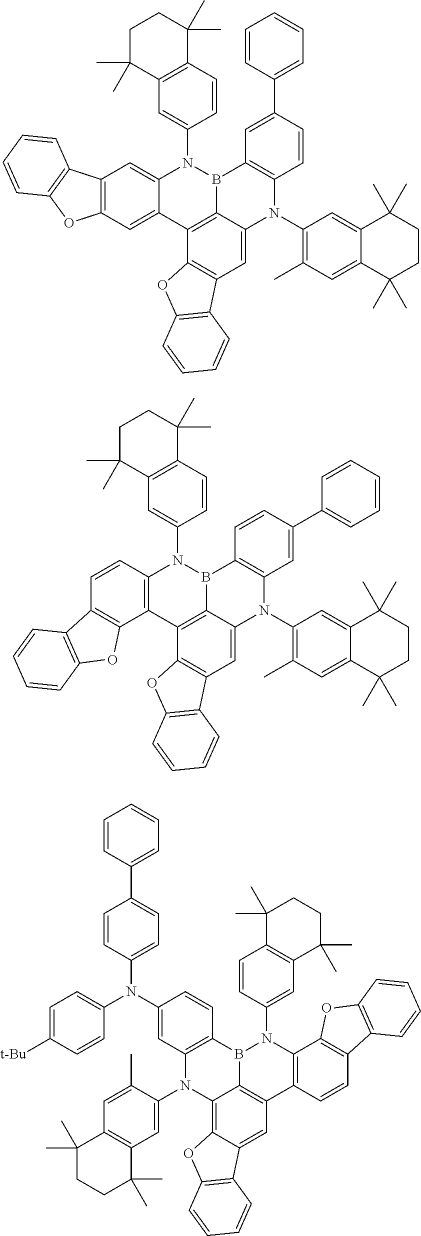 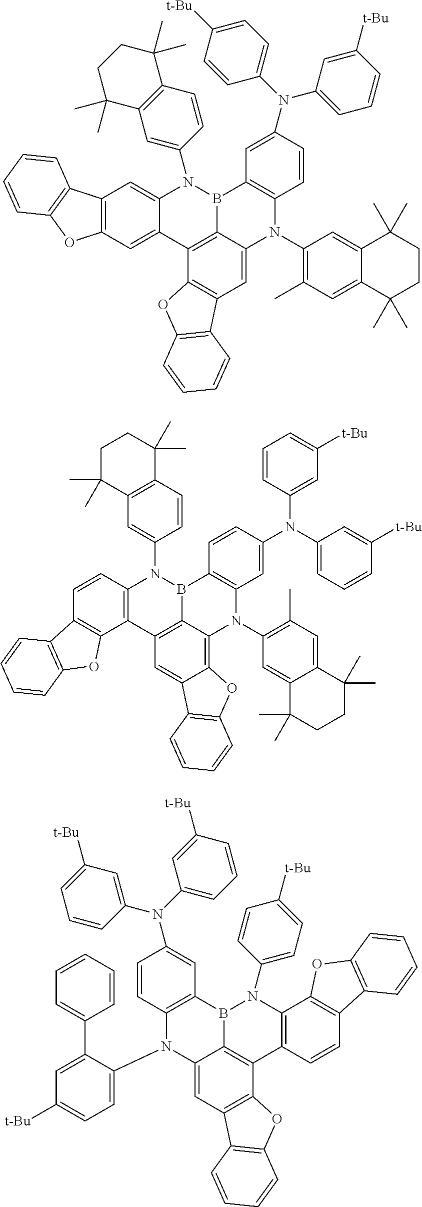 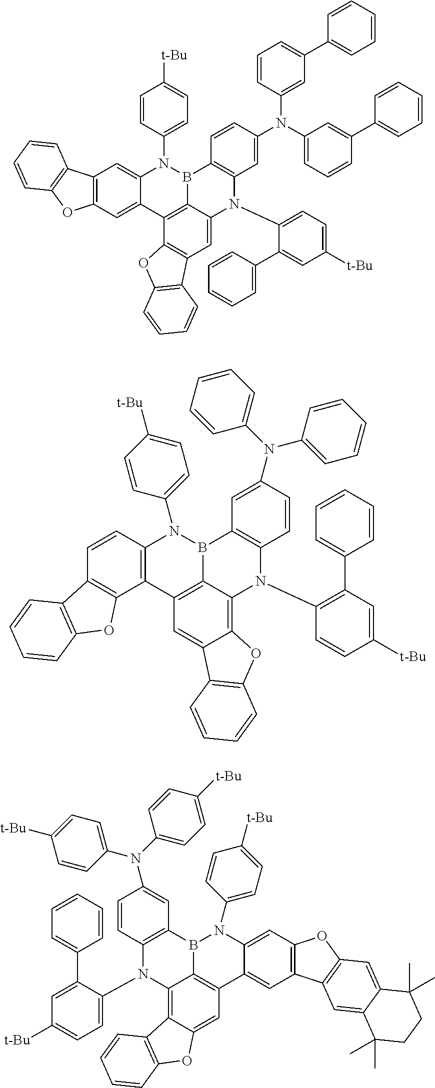 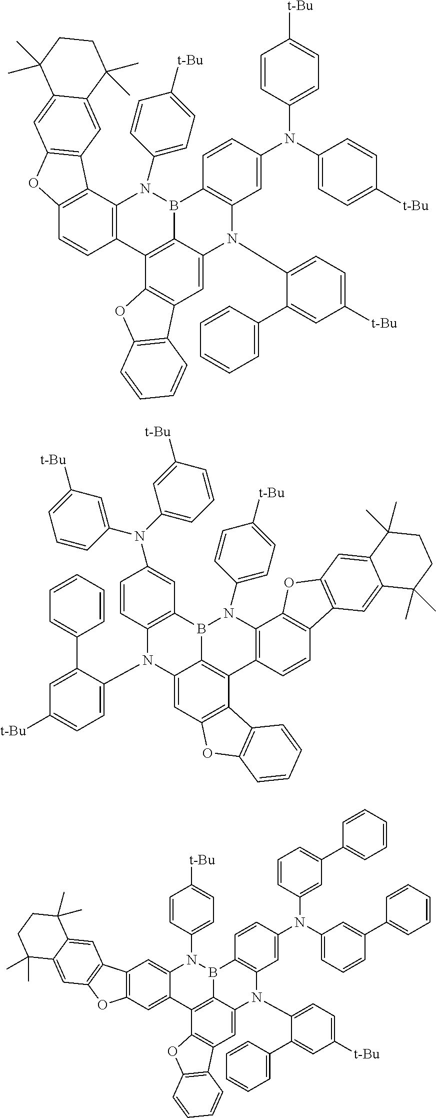 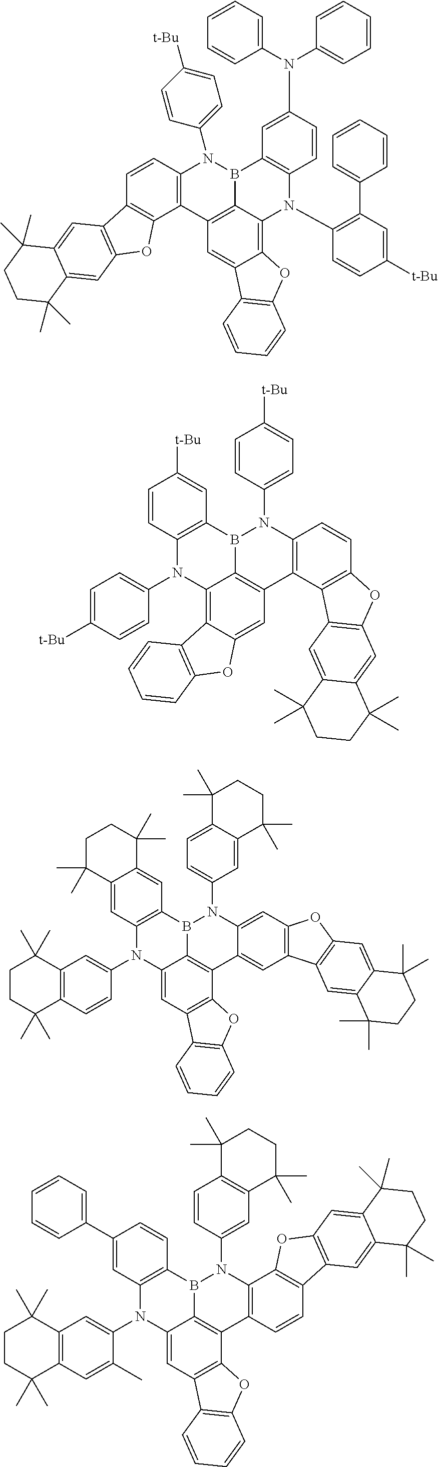 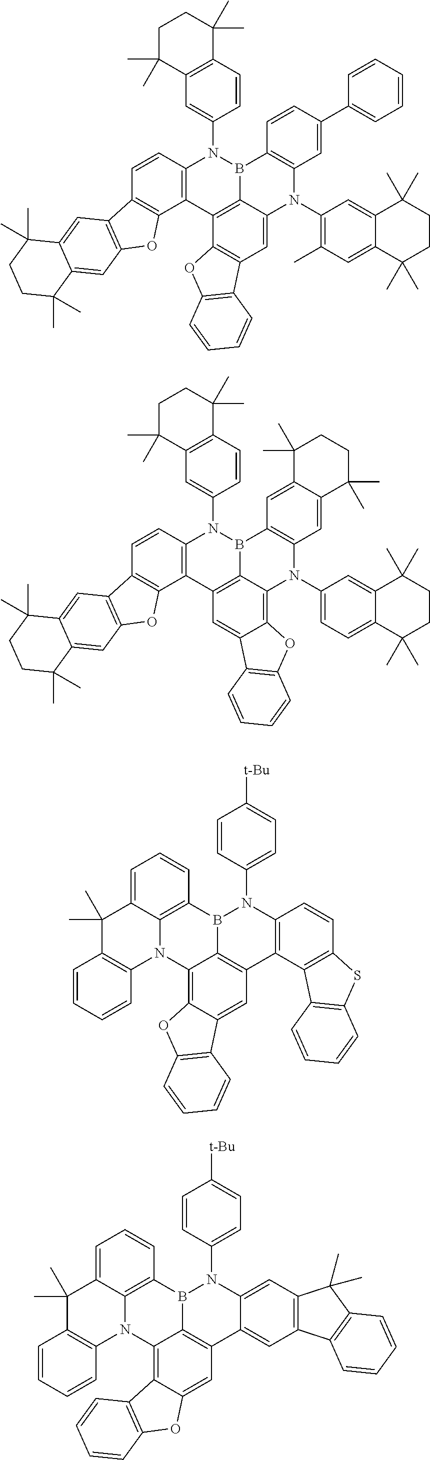 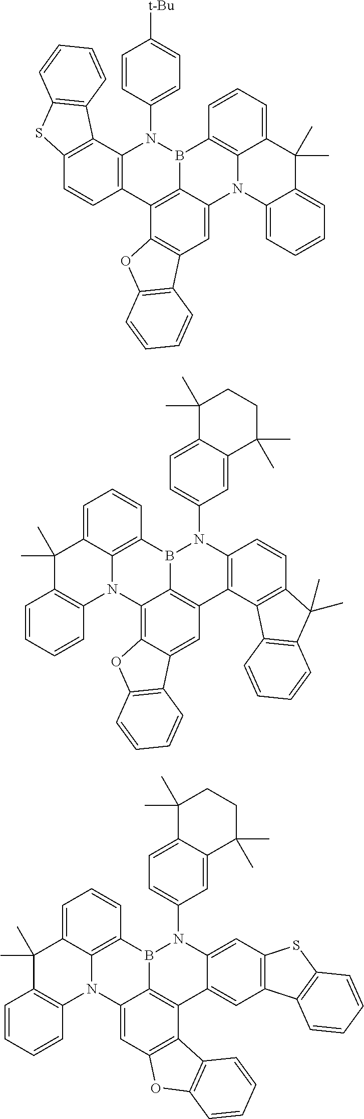 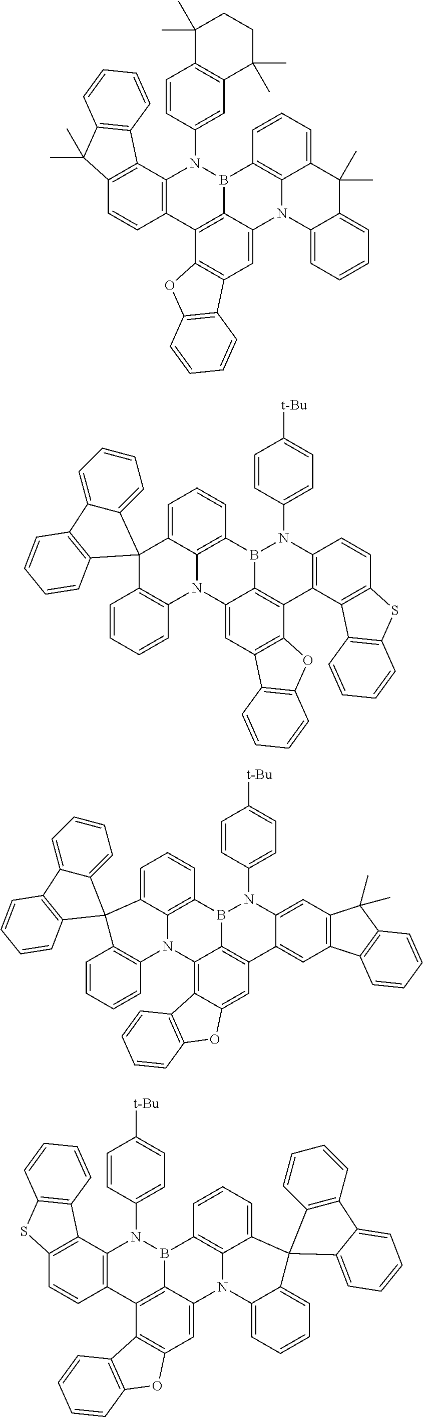 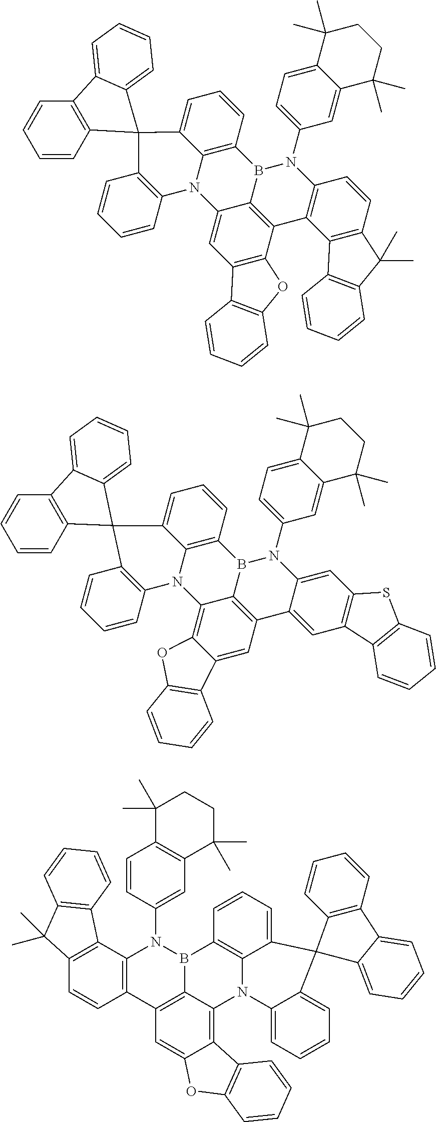 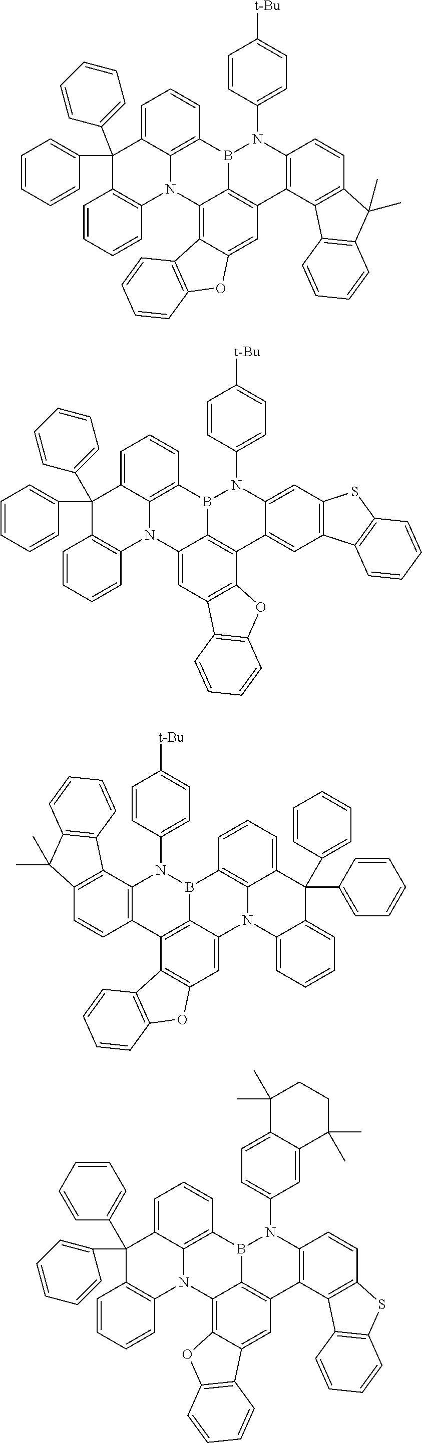 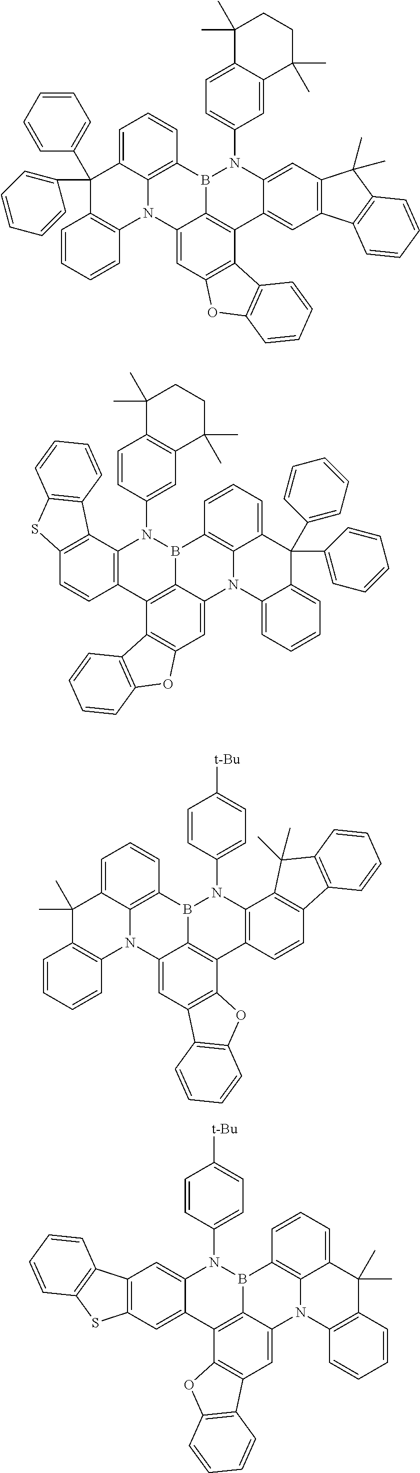 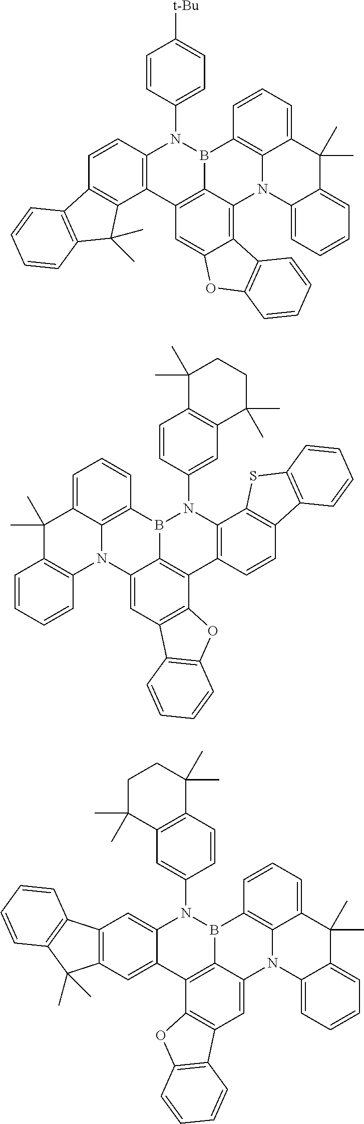 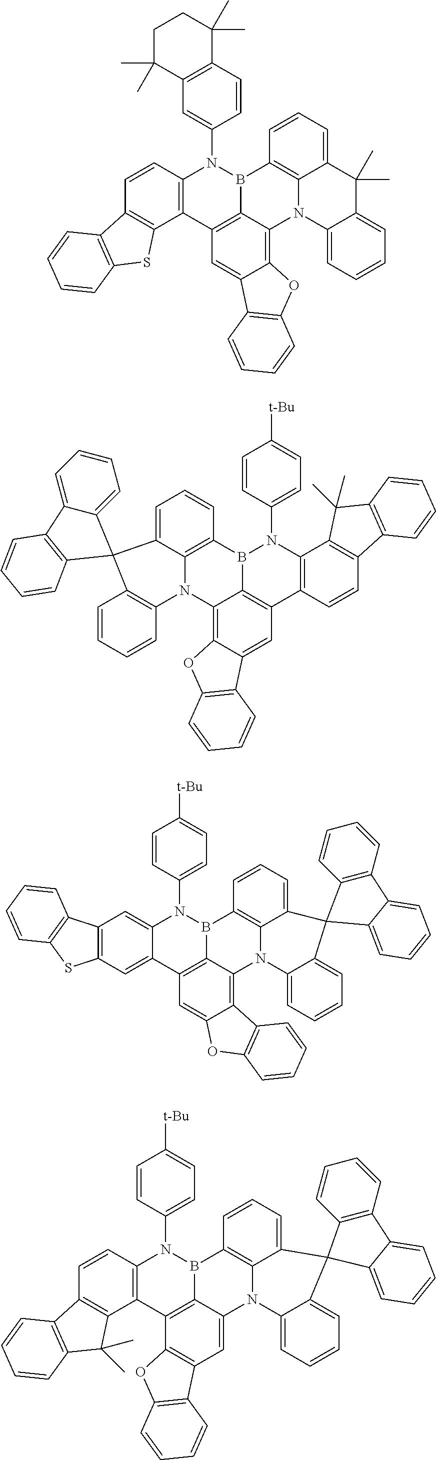 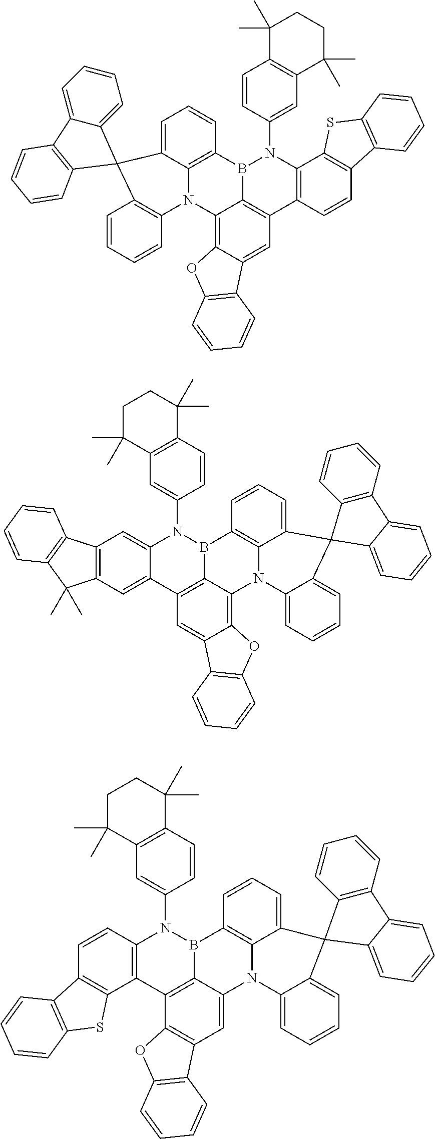 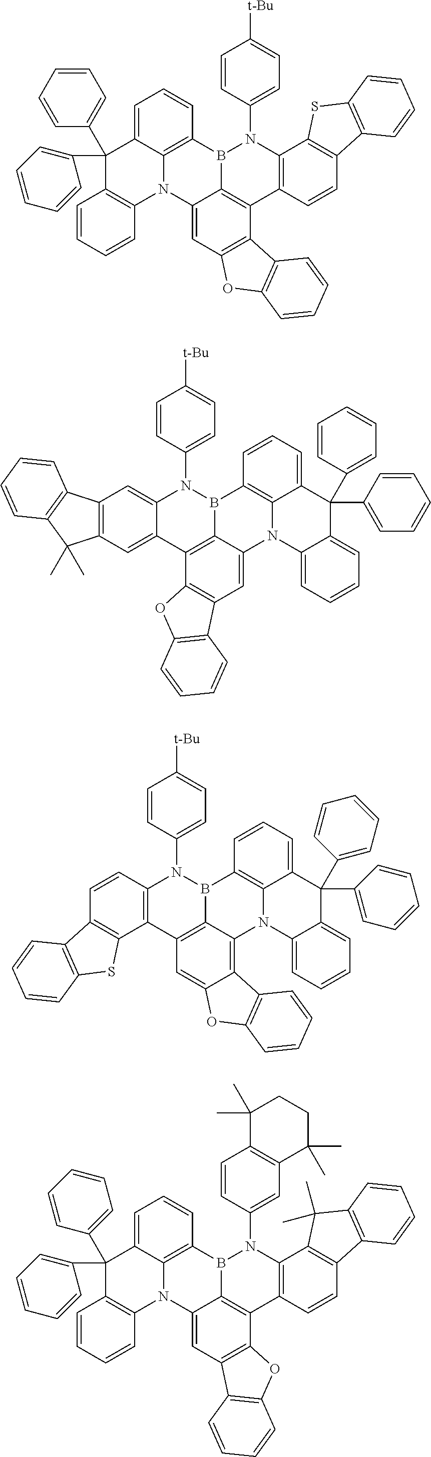 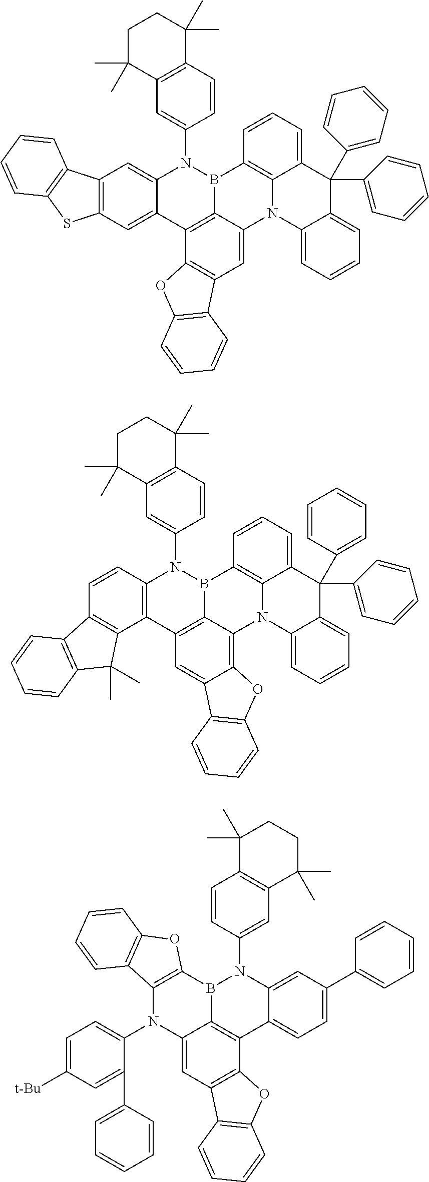 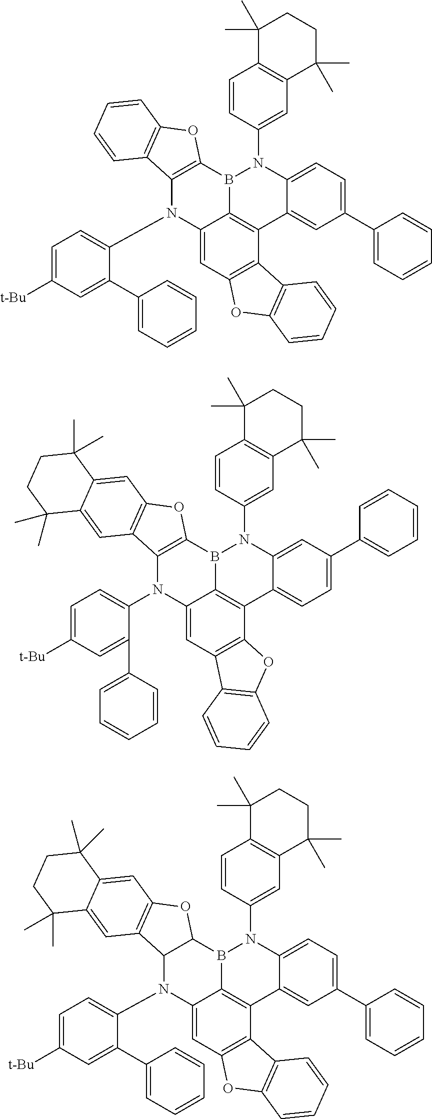 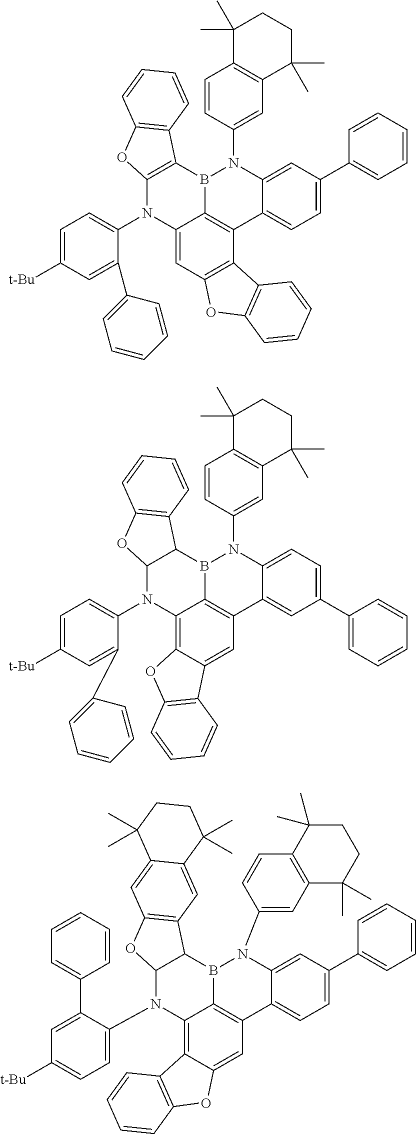 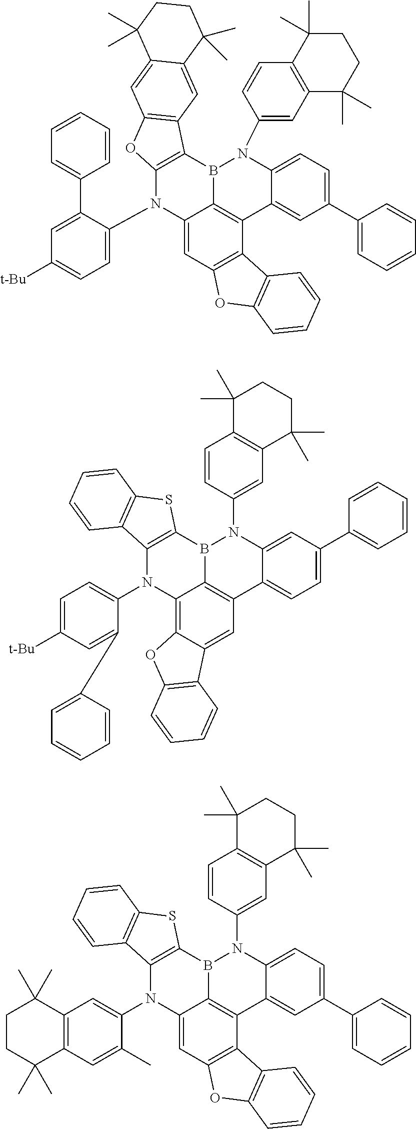 [SMILES: CC(C)(C)c1ccc(N2c3cc4oc5ccccc5c4c4c3B(c3c2oc2cc5c(cc32)C(C)(C)CCC5(C)C)N(c2ccc3c(c2)C(C)(C)CCC3(C)C)c2ccc(-c3ccccc3)cc2-4)c(-c2ccccc2)c1 ; CC(C)(C)c1ccc(N2c3c(sc4ccccc34)B3c4c(cc5c(oc6ccccc65)c42)-c2ccc(-c4ccccc4)cc2N3c2ccc3c(c2)C(C)(C)CCC3(C)C)c(-c2ccccc2)c1 ; Cc1cc2c(cc1N1c3cc4oc5ccccc5c4c4c3B(c3sc5ccccc5c31)N(c1ccc3c(c1)C(C)(C)CCC3(C)C)c1ccc(-c3ccccc3)cc1-4)C(C)(C)CCC2(C)C] 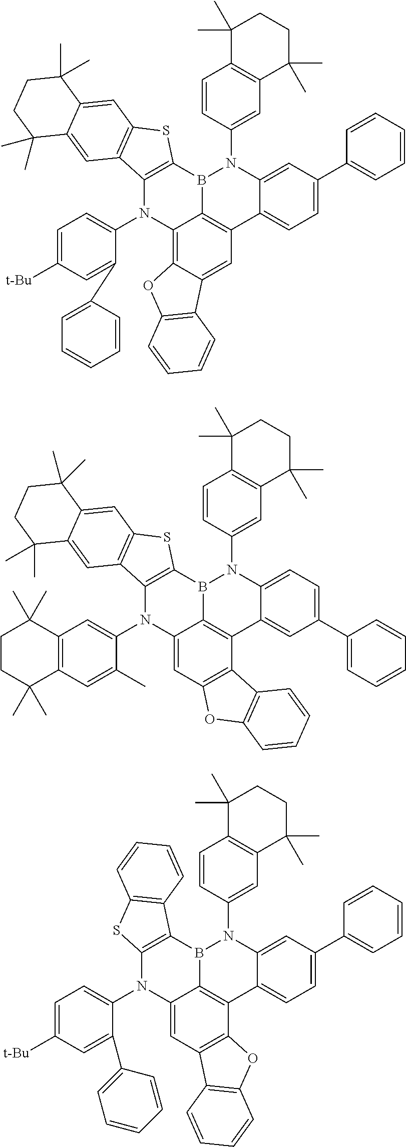 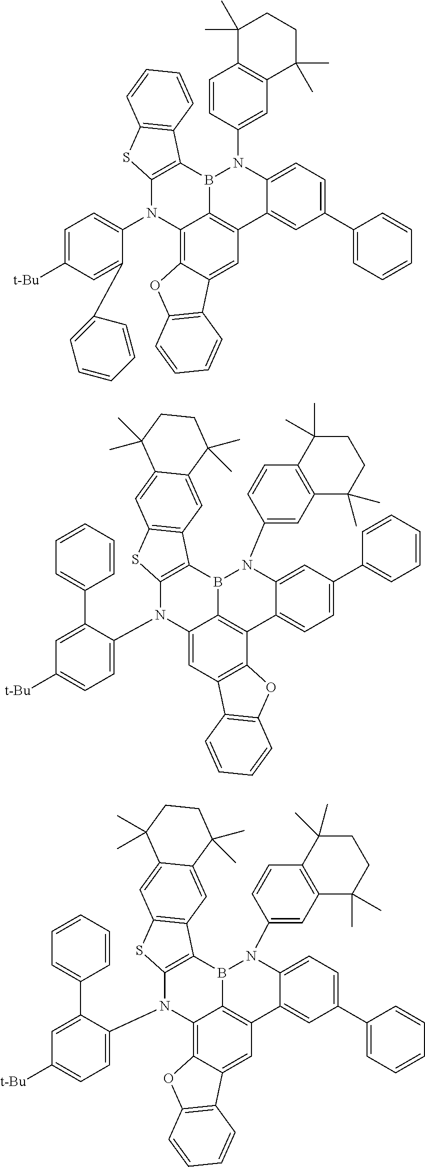 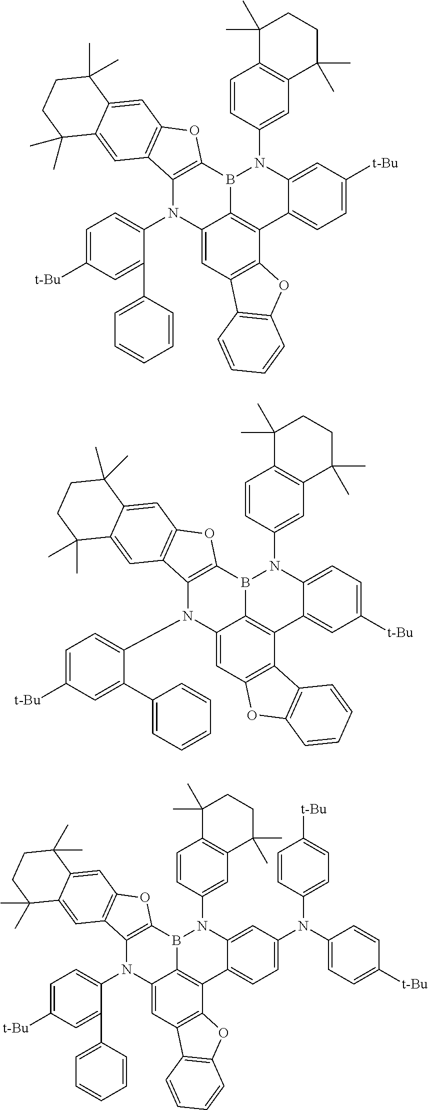 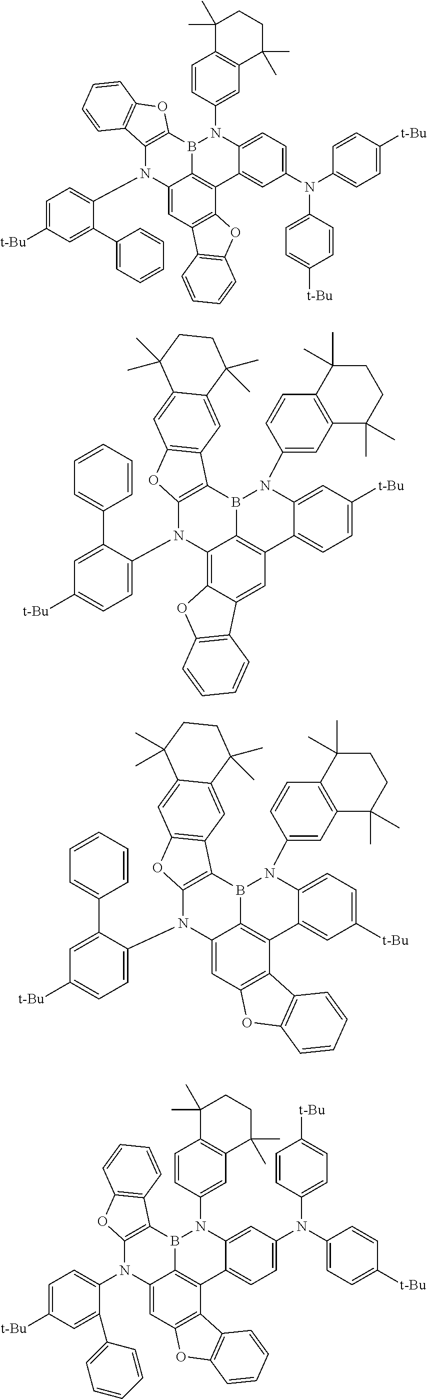 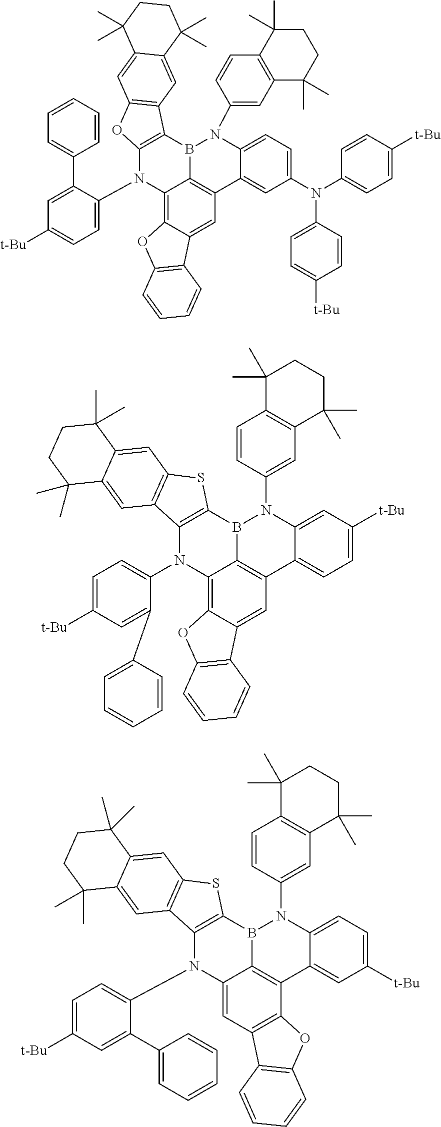 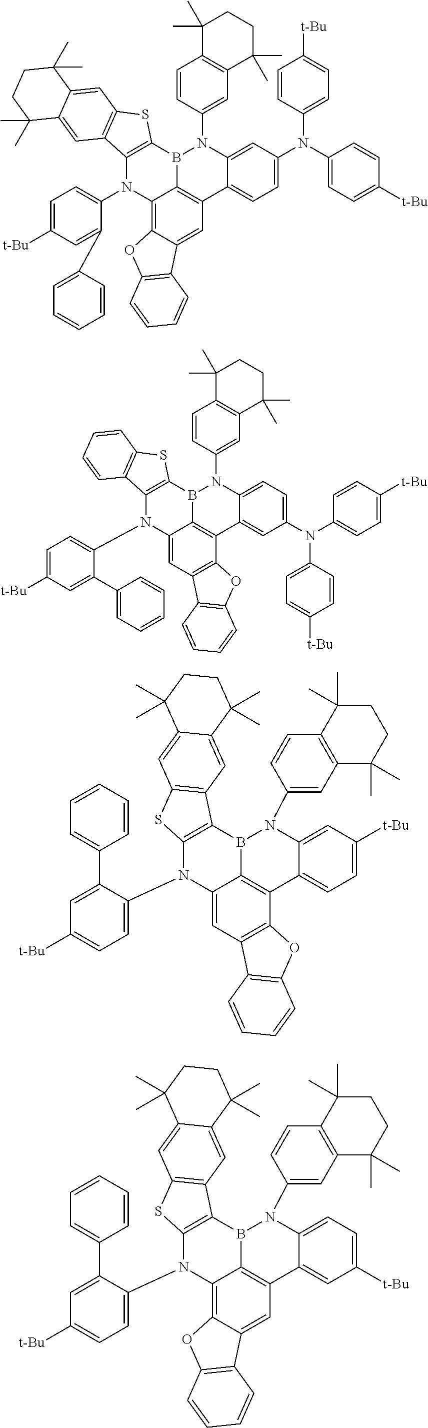 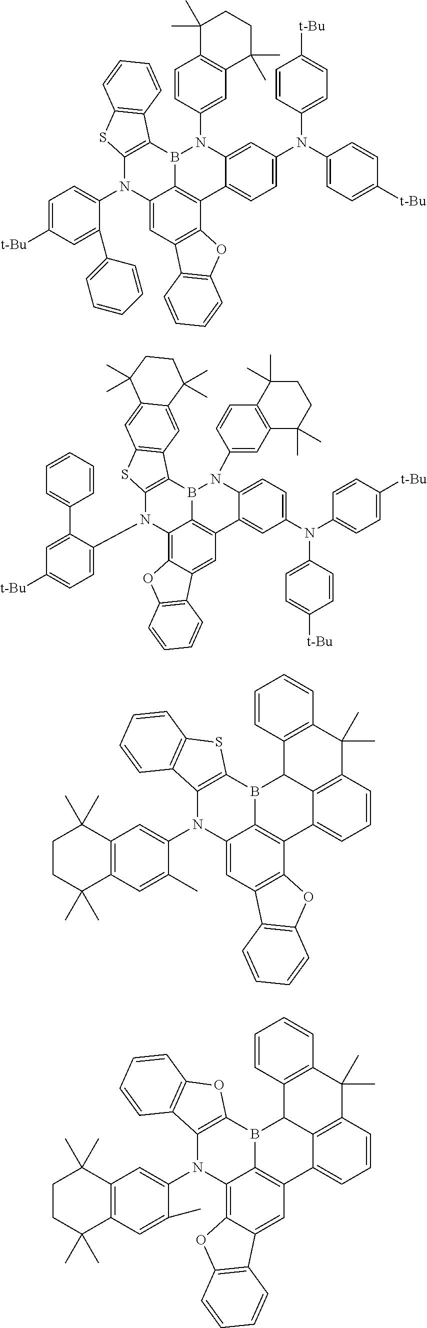 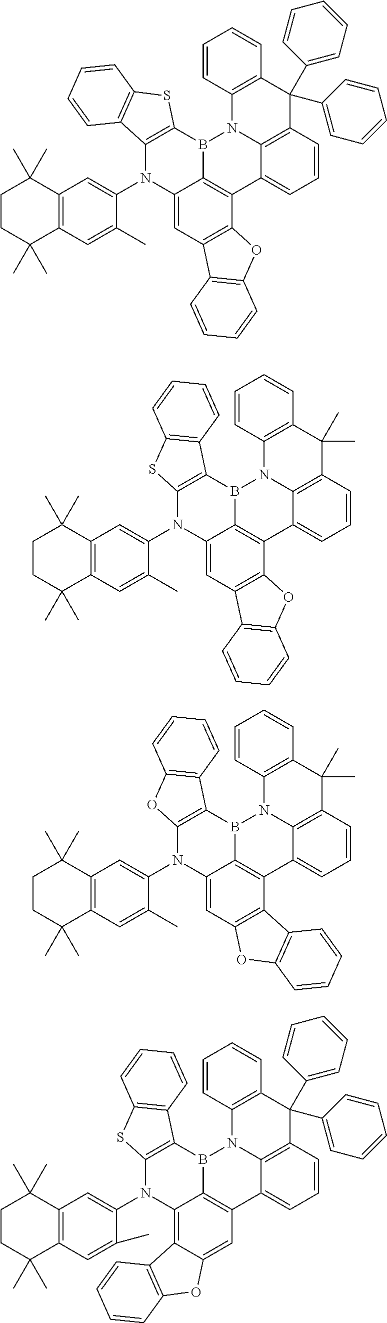 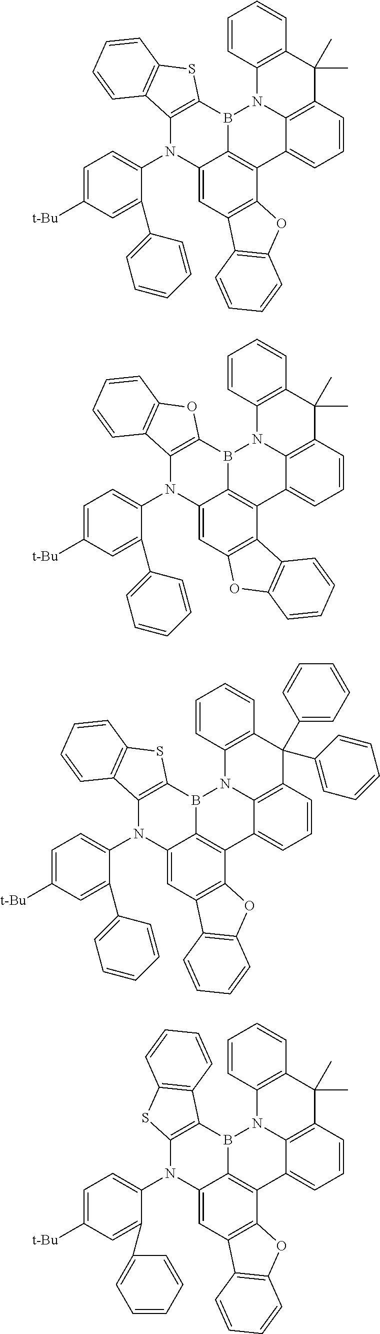 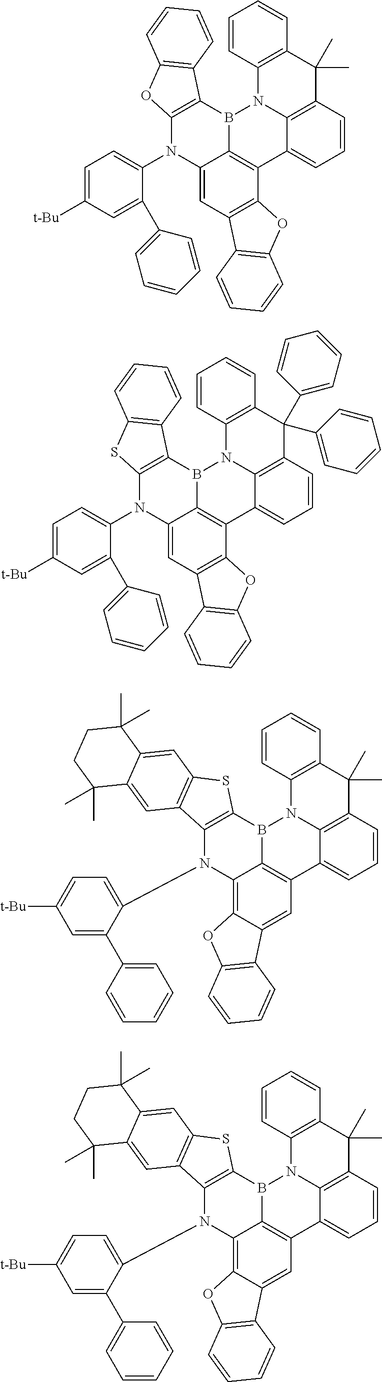 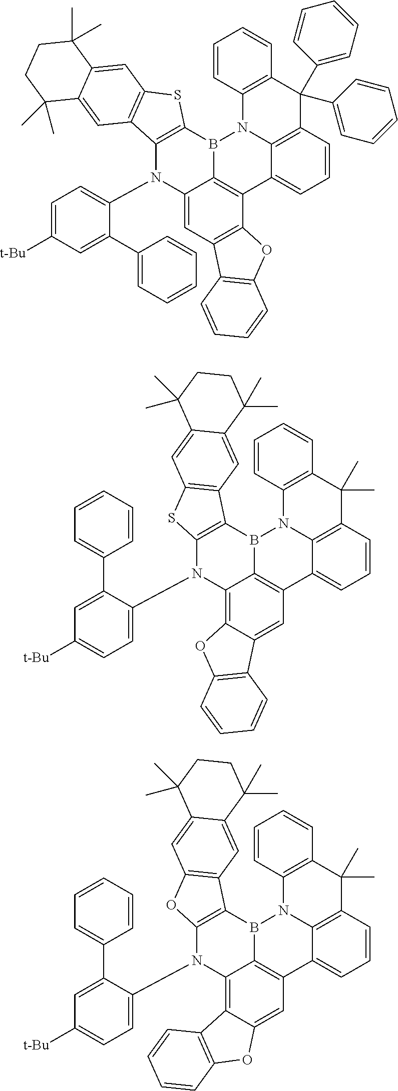 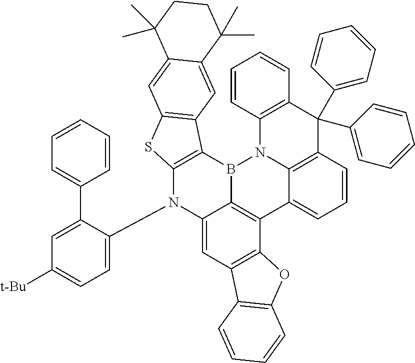 [SMILES: CC(C)(C)c1ccc(N2c3cc4c(oc5ccccc54)c4c3B(c3c2sc2cc5c(cc32)C(C)(C)CCC5(C)C)N2c3ccccc3C(c3ccccc3)(c3ccccc3)c3cccc-4c32)c(-c2ccccc2)c1] 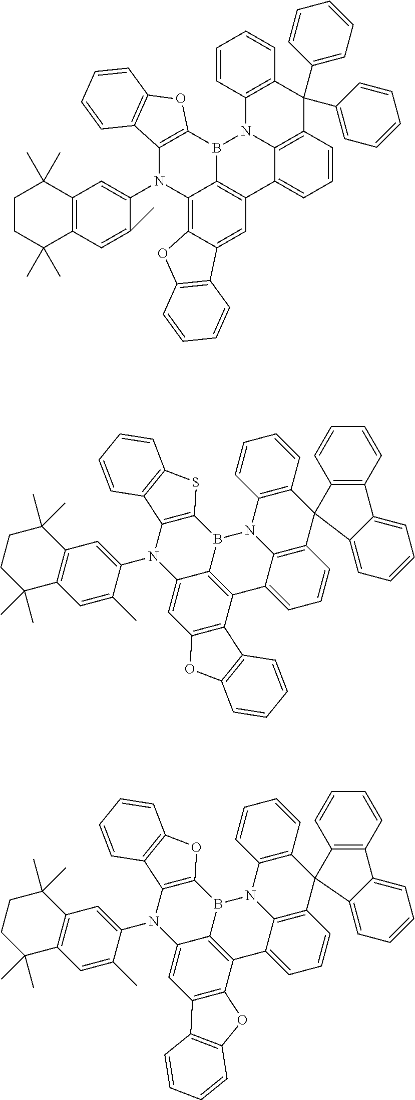 [SMILES: Cc1cc2c(cc1N1c3c(oc4ccccc34)B3c4c(cc5c(oc6ccccc65)c41)-c1cccc4c1N3c1ccccc1C4(c1ccccc1)c1ccccc1)C(C)(C)CCC2(C)C ; Cc1cc2c(cc1N1c3cc4oc5ccccc5c4c4c3B(c3sc5ccccc5c31)N1c3ccccc3C3(c5ccccc5-c5ccccc53)c3cccc-4c31)C(C)(C)CCC2(C)C ; Cc1cc2c(cc1N1c3cc4c(oc5ccccc54)c4c3B(c3oc5ccccc5c31)N1c3ccccc3C3(c5ccccc5-c5ccccc53)c3cccc-4c31)C(C)(C)CCC2(C)C] 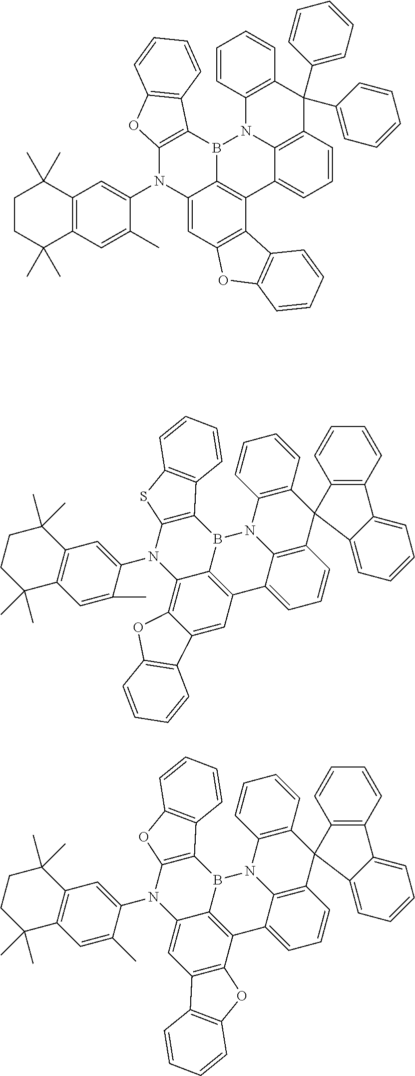 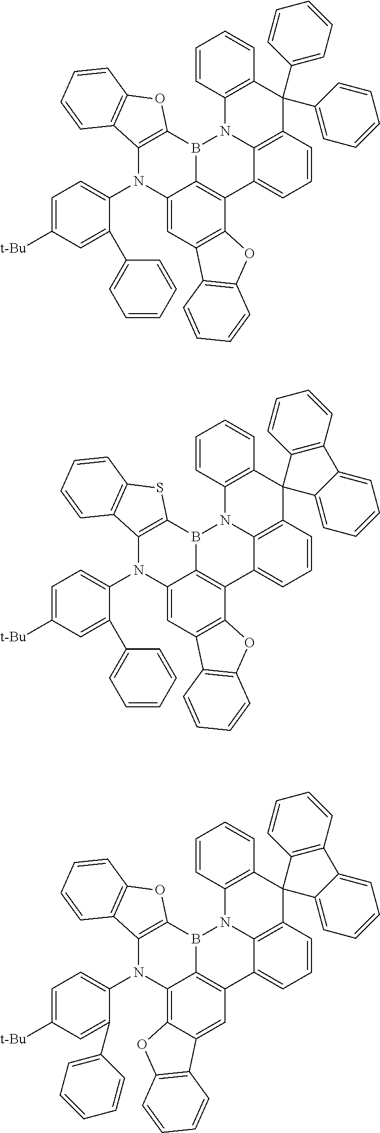 [SMILES: CC(C)(C)c1ccc(N2c3cc4c(oc5ccccc54)c4c3B(c3oc5ccccc5c32)N2c3ccccc3C(c3ccccc3)(c3ccccc3)c3cccc-4c32)c(-c2ccccc2)c1 ; CC(C)(C)c1ccc(N2c3cc4c(oc5ccccc54)c4c3B(c3sc5ccccc5c32)N2c3ccccc3C3(c5ccccc5-c5ccccc53)c3cccc-4c32)c(-c2ccccc2)c1 ; CC(C)(C)c1ccc(N2c3c(oc4ccccc34)B3c4c(cc5c(oc6ccccc65)c42)-c2cccc4c2N3c2ccccc2C42c3ccccc3-c3ccccc32)c(-c2ccccc2)c1] 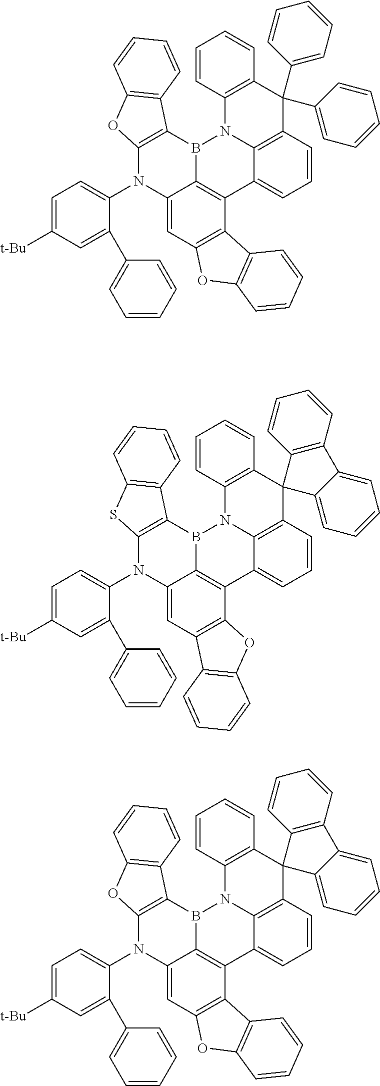 [SMILES: CC(C)(C)c1ccc(N2c3cc4oc5ccccc5c4c4c3B(c3c2oc2ccccc32)N2c3ccccc3C(c3ccccc3)(c3ccccc3)c3cccc-4c32)c(-c2ccccc2)c1 ; CC(C)(C)c1ccc(N2c3cc4c(oc5ccccc54)c4c3B(c3c2sc2ccccc32)N2c3ccccc3C3(c5ccccc5-c5ccccc53)c3cccc-4c32)c(-c2ccccc2)c1 ; CC(C)(C)c1ccc(N2c3cc4oc5ccccc5c4c4c3B(c3c2oc2ccccc32)N2c3ccccc3C3(c5ccccc5-c5ccccc53)c3cccc-4c32)c(-c2ccccc2)c1] 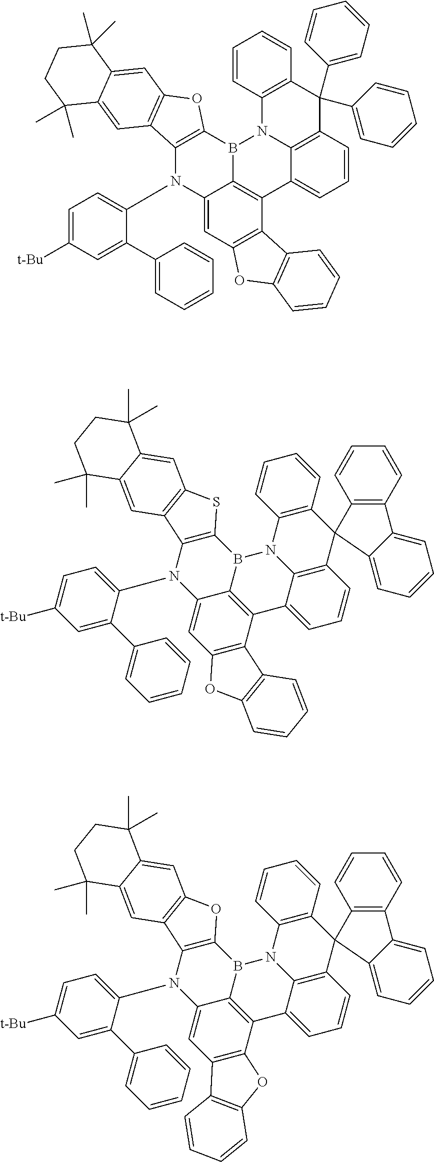 [SMILES: CC(C)(C)c1ccc(N2c3cc4oc5ccccc5c4c4c3B(c3oc5cc6c(cc5c32)C(C)(C)CCC6(C)C)N2c3ccccc3C(c3ccccc3)(c3ccccc3)c3cccc-4c32)c(-c2ccccc2)c1 ; CC(C)(C)c1ccc(N2c3cc4oc5ccccc5c4c4c3B(c3sc5cc6c(cc5c32)C(C)(C)CCC6(C)C)N2c3ccccc3C3(c5ccccc5-c5ccccc53)c3cccc-4c32)c(-c2ccccc2)c1 ; CC(C)(C)c1ccc(N2c3cc4c(oc5ccccc54)c4c3B(c3oc5cc6c(cc5c32)C(C)(C)CCC6(C)C)N2c3ccccc3C3(c5ccccc5-c5ccccc53)c3cccc-4c32)c(-c2ccccc2)c1] 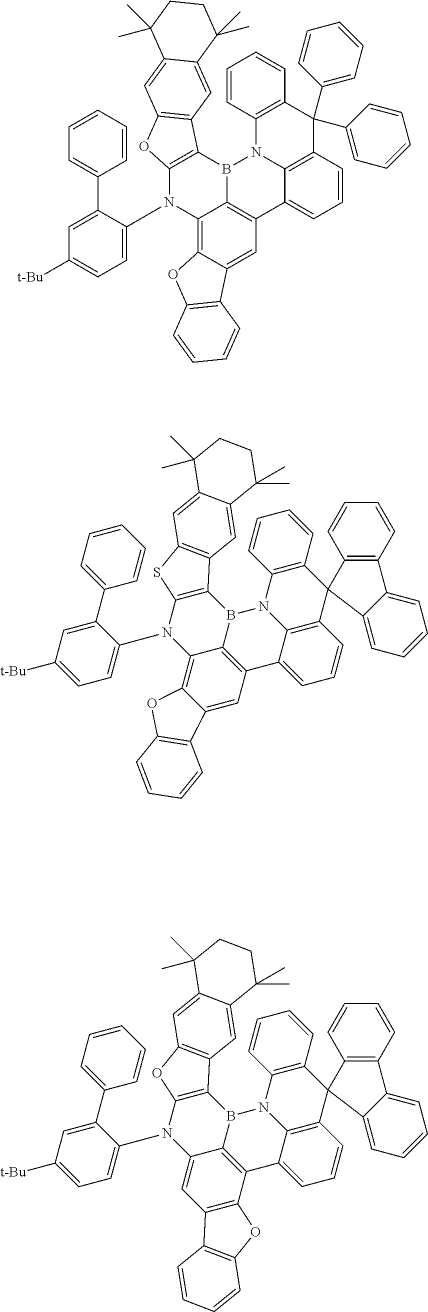 [SMILES: CC(C)(C)c1ccc(N2c3oc4cc5c(cc4c3B3c4c(cc6c(oc7ccccc76)c42)-c2cccc4c2N3c2ccccc2C4(c2ccccc2)c2ccccc2)C(C)(C)CCC5(C)C)c(-c2ccccc2)c1 ; CC(C)(C)c1ccc(N2c3sc4cc5c(cc4c3B3c4c(cc6c(oc7ccccc76)c42)-c2cccc4c2N3c2ccccc2C42c3ccccc3-c3ccccc32)C(C)(C)CCC5(C)C)c(-c2ccccc2)c1 ; CC(C)(C)c1ccc(N2c3cc4c(oc5ccccc54)c4c3B(c3c2oc2cc5c(cc32)C(C)(C)CCC5(C)C)N2c3ccccc3C3(c5ccccc5-c5ccccc53)c3cccc-4c32)c(-c2ccccc2)c1] 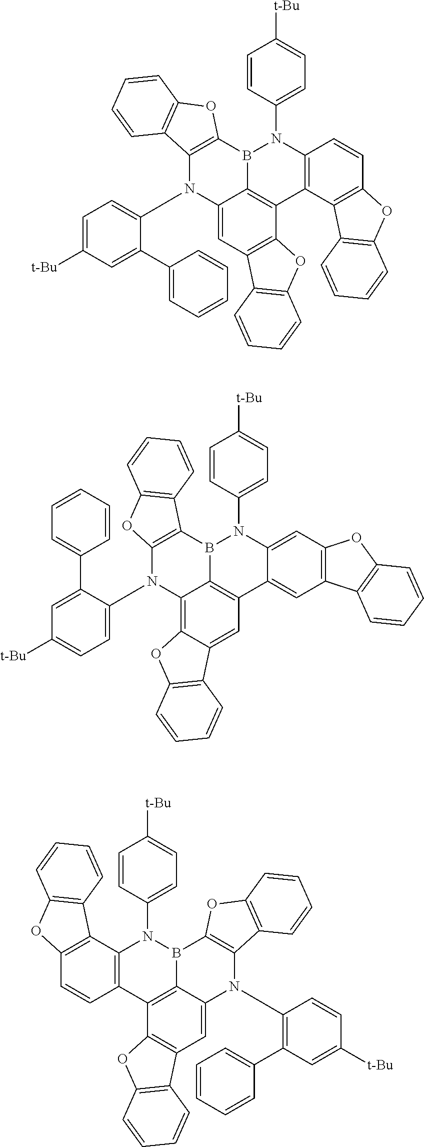 [SMILES: CC(C)(C)c1ccc(N2B3c4oc5ccccc5c4N(c4ccc(C(C)(C)C)cc4-c4ccccc4)c4cc5c(oc6ccccc65)c(c43)-c3c2ccc2oc4ccccc4c32)cc1 ; CC(C)(C)c1ccc(N2B3c4c(cc5c(oc6ccccc65)c4N(c4ccc(C(C)(C)C)cc4-c4ccccc4)c4oc5ccccc5c43)-c3cc4c(cc32)oc2ccccc24)cc1 ; CC(C)(C)c1ccc(N2B3c4oc5ccccc5c4N(c4ccc(C(C)(C)C)cc4-c4ccccc4)c4cc5c(oc6ccccc65)c(c43)-c3ccc4oc5ccccc5c4c32)cc1] 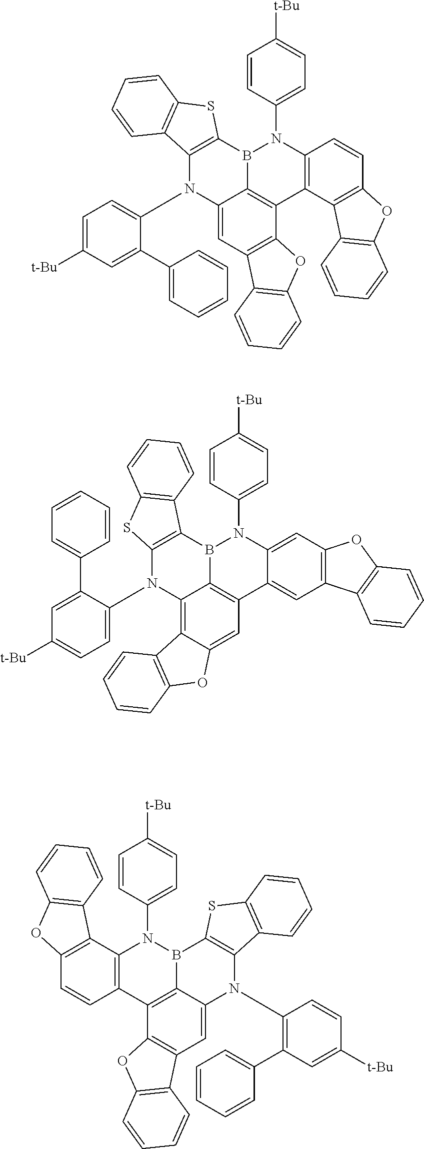 [SMILES: CC(C)(C)c1ccc(N2B3c4sc5ccccc5c4N(c4ccc(C(C)(C)C)cc4-c4ccccc4)c4cc5c(oc6ccccc65)c(c43)-c3c2ccc2oc4ccccc4c32)cc1 ; CC(C)(C)c1ccc(N2B3c4c(cc5oc6ccccc6c5c4N(c4ccc(C(C)(C)C)cc4-c4ccccc4)c4sc5ccccc5c43)-c3cc4c(cc32)oc2ccccc24)cc1 ; CC(C)(C)c1ccc(N2B3c4sc5ccccc5c4N(c4ccc(C(C)(C)C)cc4-c4ccccc4)c4cc5c(oc6ccccc65)c(c43)-c3ccc4oc5ccccc5c4c32)cc1] 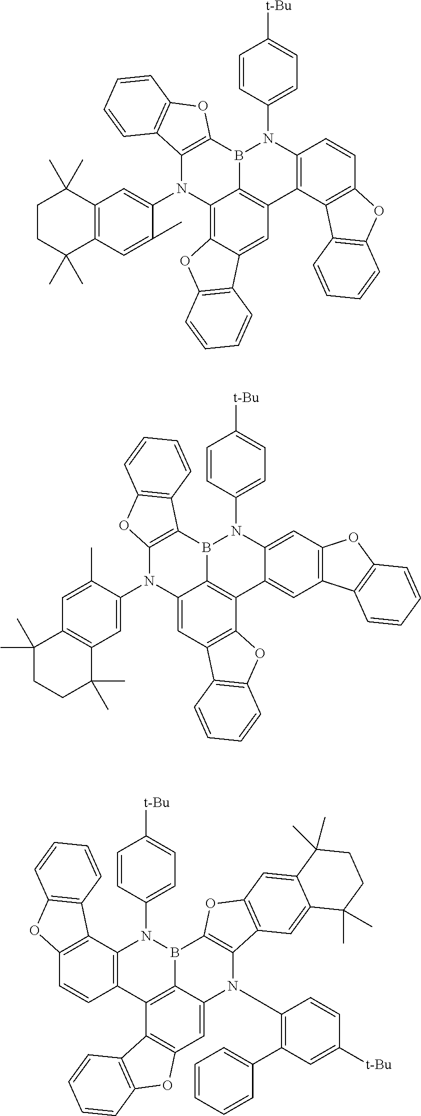 [SMILES: Cc1cc2c(cc1N1c3c(oc4ccccc34)B3c4c(cc5c(oc6ccccc65)c41)-c1c(ccc4oc5ccccc5c14)N3c1ccc(C(C)(C)C)cc1)C(C)(C)CCC2(C)C ; Cc1cc2c(cc1N1c3cc4c(oc5ccccc54)c4c3B(c3c1oc1ccccc31)N(c1ccc(C(C)(C)C)cc1)c1cc3oc5ccccc5c3cc1-4)C(C)(C)CCC2(C)C ; CC(C)(C)c1ccc(N2B3c4oc5cc6c(cc5c4N(c4ccc(C(C)(C)C)cc4-c4ccccc4)c4cc5oc7ccccc7c5c(c43)-c3ccc4oc5ccccc5c4c32)C(C)(C)CCC6(C)C)cc1] 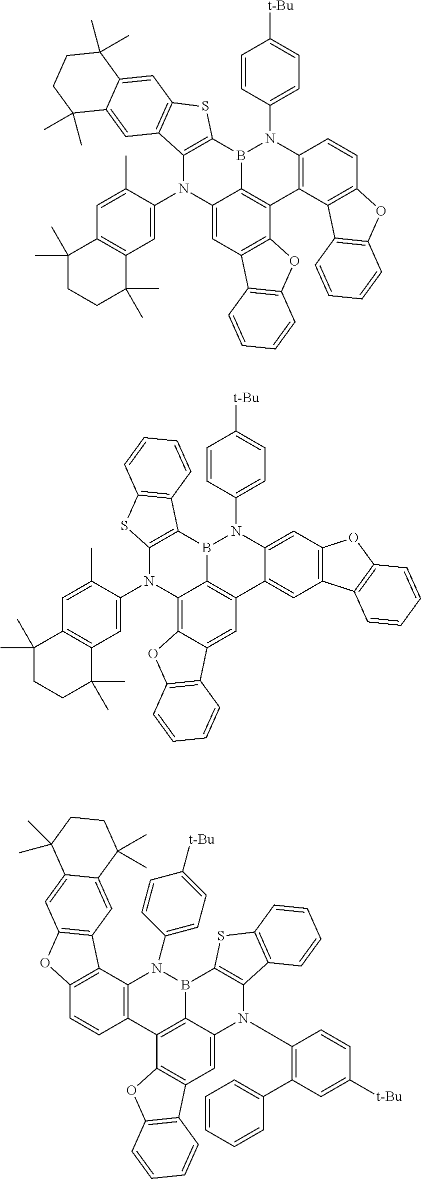 [SMILES: Cc1cc2c(cc1N1c3cc4c(oc5ccccc54)c4c3B(c3sc5cc6c(cc5c31)C(C)(C)CCC6(C)C)N(c1ccc(C(C)(C)C)cc1)c1ccc3oc5ccccc5c3c1-4)C(C)(C)CCC2(C)C ; Cc1cc2c(cc1N1c3sc4ccccc4c3B3c4c(cc5c(oc6ccccc65)c41)-c1cc4c(cc1N3c1ccc(C(C)(C)C)cc1)oc1ccccc14)C(C)(C)CCC2(C)C ; CC(C)(C)c1ccc(N2B3c4sc5ccccc5c4N(c4ccc(C(C)(C)C)cc4-c4ccccc4)c4cc5c(oc6ccccc65)c(c43)-c3ccc4oc5cc6c(cc5c4c32)C(C)(C)CCC6(C)C)cc1] 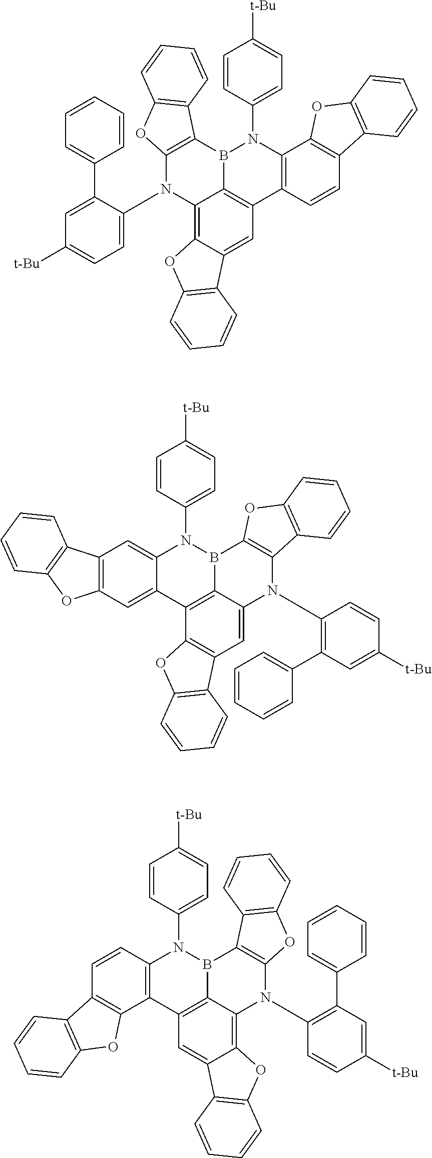 [SMILES: CC(C)(C)c1ccc(N2B3c4c(cc5c(oc6ccccc65)c4N(c4ccc(C(C)(C)C)cc4-c4ccccc4)c4oc5ccccc5c43)-c3ccc4c(oc5ccccc54)c32)cc1 ; CC(C)(C)c1ccc(N2B3c4oc5ccccc5c4N(c4ccc(C(C)(C)C)cc4-c4ccccc4)c4cc5c(oc6ccccc65)c(c43)-c3cc4oc5ccccc5c4cc32)cc1 ; CC(C)(C)c1ccc(N2B3c4c(cc5c(oc6ccccc65)c4N(c4ccc(C(C)(C)C)cc4-c4ccccc4)c4oc5ccccc5c43)-c3c2ccc2c3oc3ccccc32)cc1] 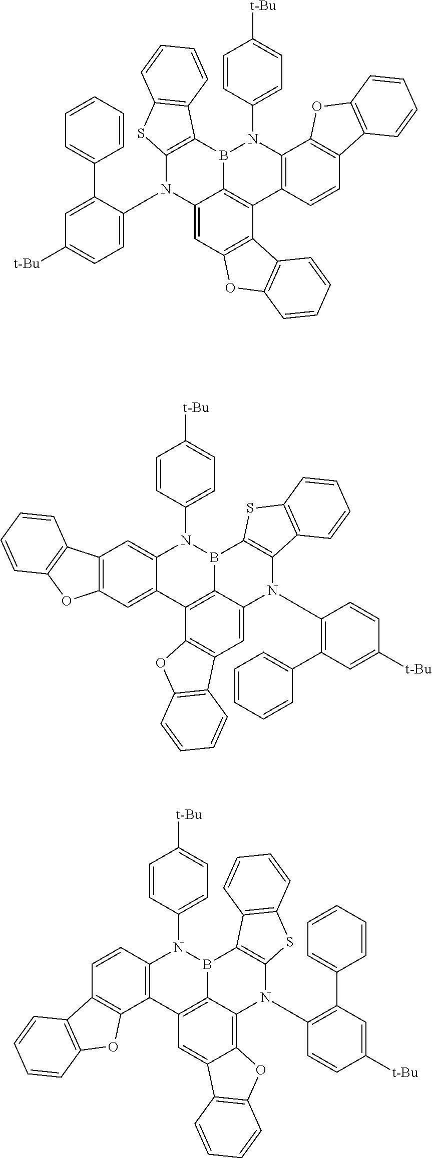 [SMILES: CC(C)(C)c1ccc(N2B3c4c(cc5oc6ccccc6c5c4-c4ccc5c(oc6ccccc65)c42)N(c2ccc(C(C)(C)C)cc2-c2ccccc2)c2sc4ccccc4c23)cc1 ; CC(C)(C)c1ccc(N2B3c4sc5ccccc5c4N(c4ccc(C(C)(C)C)cc4-c4ccccc4)c4cc5c(oc6ccccc65)c(c43)-c3cc4oc5ccccc5c4cc32)cc1 ; CC(C)(C)c1ccc(N2B3c4c(cc5c(oc6ccccc65)c4N(c4ccc(C(C)(C)C)cc4-c4ccccc4)c4sc5ccccc5c43)-c3c2ccc2c3oc3ccccc32)cc1] 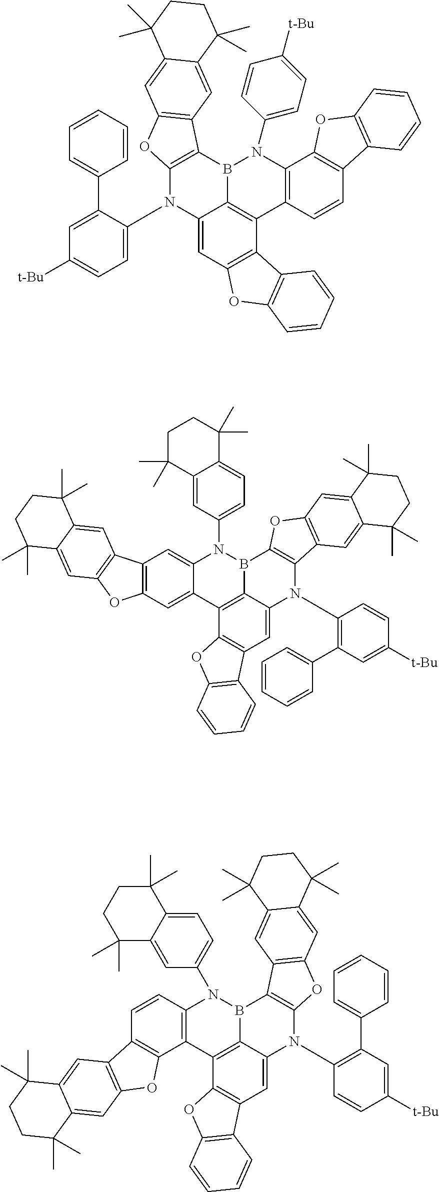 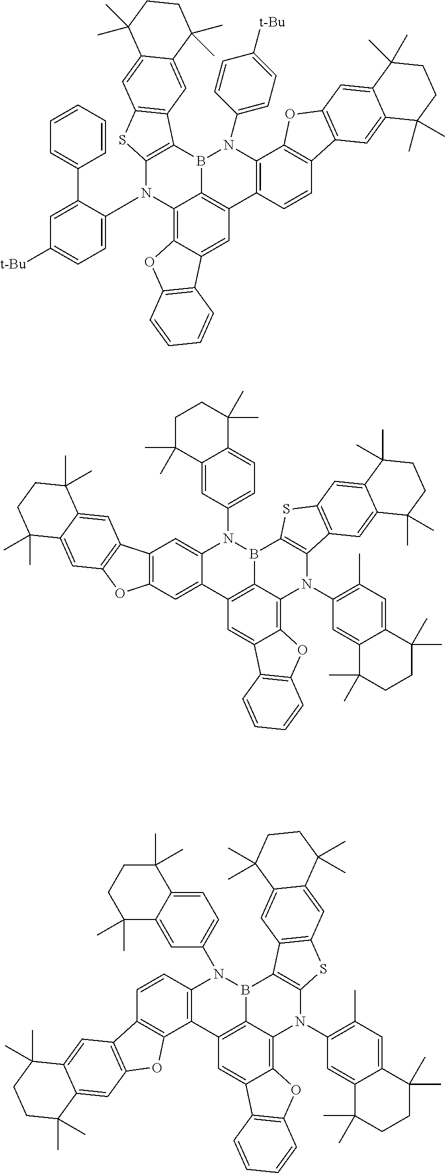 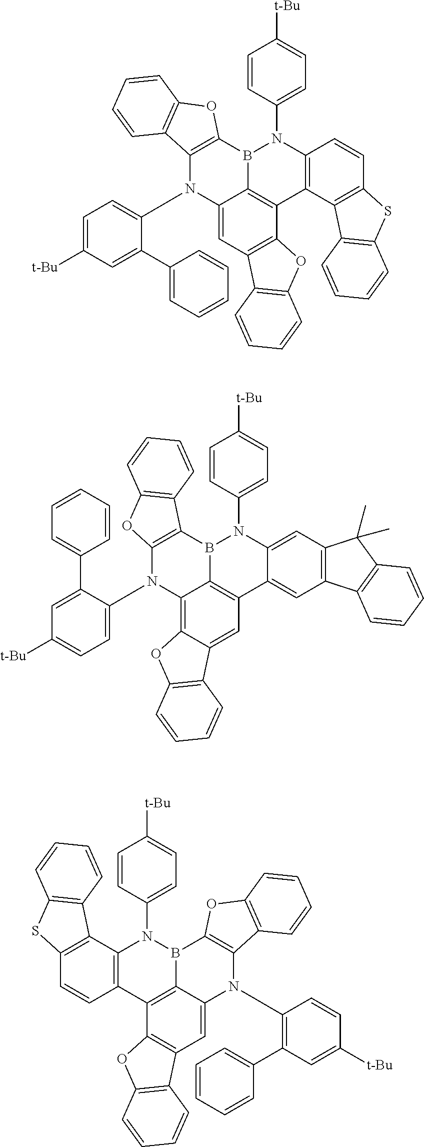 [SMILES: CC(C)(C)c1ccc(N2B3c4oc5ccccc5c4N(c4ccc(C(C)(C)C)cc4-c4ccccc4)c4cc5c(oc6ccccc65)c(c43)-c3c2ccc2sc4ccccc4c32)cc1 ; CC(C)(C)c1ccc(N2B3c4c(cc5c(oc6ccccc65)c4N(c4ccc(C(C)(C)C)cc4-c4ccccc4)c4oc5ccccc5c43)-c3cc4c(cc32)C(C)(C)c2ccccc2-4)cc1 ; CC(C)(C)c1ccc(N2B3c4oc5ccccc5c4N(c4ccc(C(C)(C)C)cc4-c4ccccc4)c4cc5c(oc6ccccc65)c(c43)-c3ccc4sc5ccccc5c4c32)cc1] 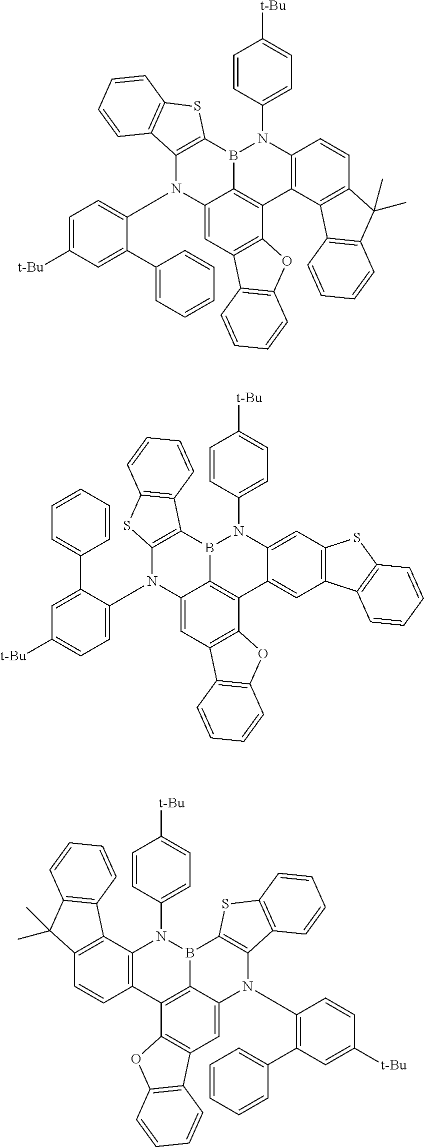 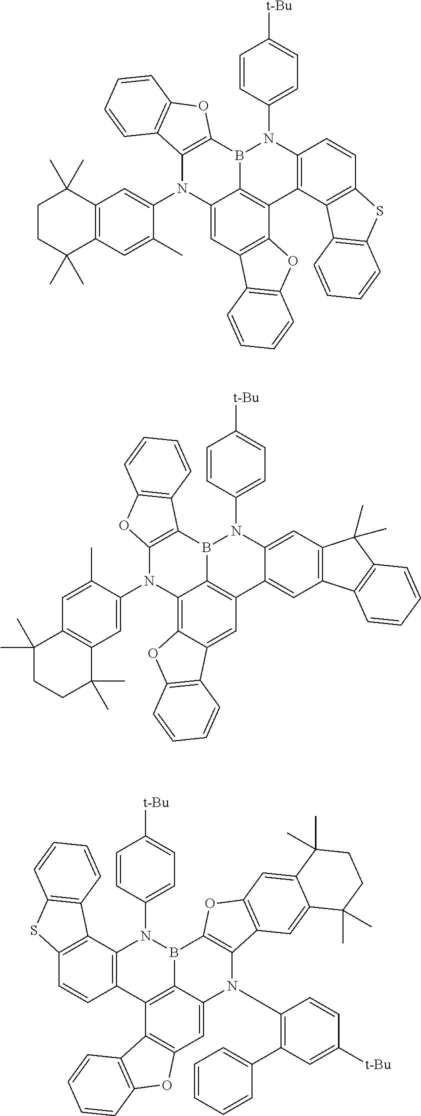 [SMILES: Cc1cc2c(cc1N1c3cc4c(oc5ccccc54)c4c3B(c3oc5ccccc5c31)N(c1ccc(C(C)(C)C)cc1)c1ccc3sc5ccccc5c3c1-4)C(C)(C)CCC2(C)C ; Cc1cc2c(cc1N1c3oc4ccccc4c3B3c4c(cc5c(oc6ccccc65)c41)-c1cc4c(cc1N3c1ccc(C(C)(C)C)cc1)C(C)(C)c1ccccc1-4)C(C)(C)CCC2(C)C ; CC(C)(C)c1ccc(N2B3c4oc5cc6c(cc5c4N(c4ccc(C(C)(C)C)cc4-c4ccccc4)c4cc5oc7ccccc7c5c(c43)-c3ccc4sc5ccccc5c4c32)C(C)(C)CCC6(C)C)cc1] 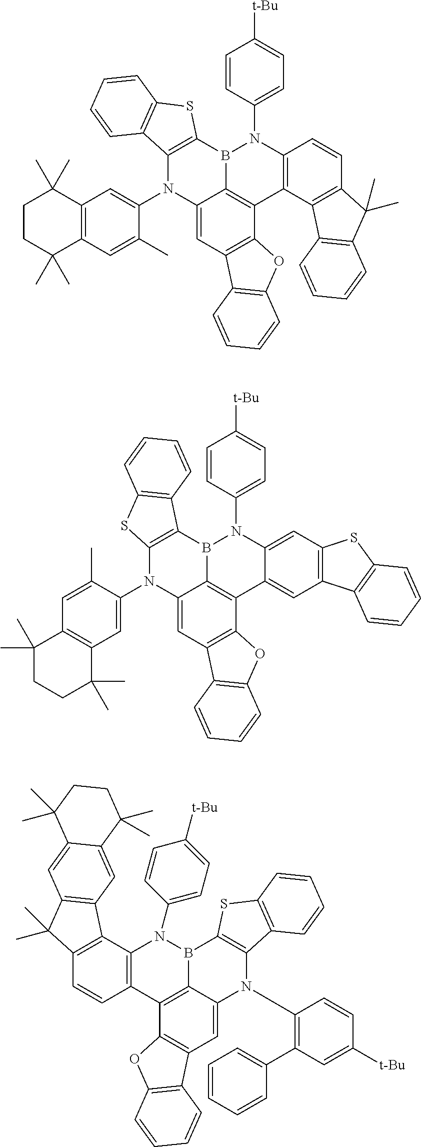 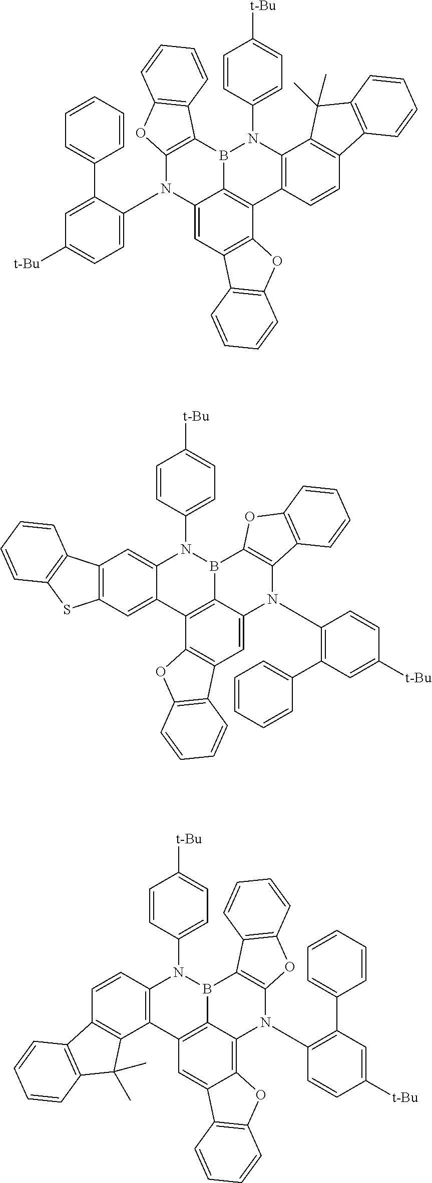 [SMILES: CC(C)(C)c1ccc(N2B3c4c(cc5c(oc6ccccc65)c4-c4ccc5c(c42)C(C)(C)c2ccccc2-5)N(c2ccc(C(C)(C)C)cc2-c2ccccc2)c2oc4ccccc4c23)cc1 ; CC(C)(C)c1ccc(N2B3c4oc5ccccc5c4N(c4ccc(C(C)(C)C)cc4-c4ccccc4)c4cc5c(oc6ccccc65)c(c43)-c3cc4sc5ccccc5c4cc32)cc1 ; CC(C)(C)c1ccc(N2B3c4c(cc5c(oc6ccccc65)c4N(c4ccc(C(C)(C)C)cc4-c4ccccc4)c4oc5ccccc5c43)-c3c2ccc2c3C(C)(C)c3ccccc3-2)cc1] 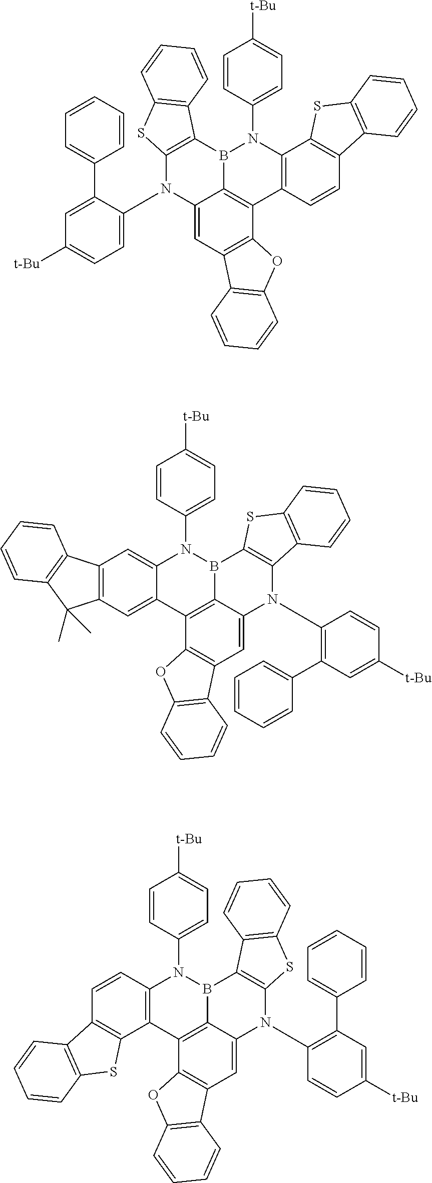 [SMILES: CC(C)(C)c1ccc(N2B3c4c(cc5c(oc6ccccc65)c4-c4ccc5c(sc6ccccc65)c42)N(c2ccc(C(C)(C)C)cc2-c2ccccc2)c2sc4ccccc4c23)cc1 ; CC(C)(C)c1ccc(N2B3c4sc5ccccc5c4N(c4ccc(C(C)(C)C)cc4-c4ccccc4)c4cc5c(oc6ccccc65)c(c43)-c3cc4c(cc32)-c2ccccc2C4(C)C)cc1 ; CC(C)(C)c1ccc(N2B3c4c(cc5c(oc6ccccc65)c4-c4c2ccc2c4sc4ccccc42)N(c2ccc(C(C)(C)C)cc2-c2ccccc2)c2sc4ccccc4c23)cc1] 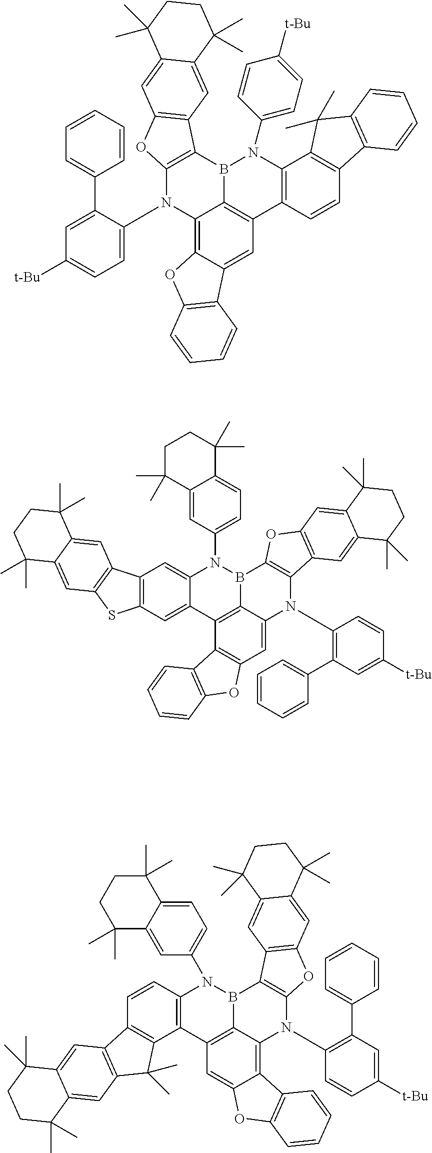 [SMILES: CC(C)(C)c1ccc(N2B3c4c(cc5c(oc6ccccc65)c4N(c4ccc(C(C)(C)C)cc4-c4ccccc4)c4oc5cc6c(cc5c43)C(C)(C)CCC6(C)C)-c3ccc4c(c32)C(C)(C)c2ccccc2-4)cc1 ; CC(C)(C)c1ccc(N2c3cc4oc5ccccc5c4c4c3B(c3oc5cc6c(cc5c32)C(C)(C)CCC6(C)C)N(c2ccc3c(c2)C(C)(C)CCC3(C)C)c2cc3c(cc2-4)sc2cc4c(cc23)C(C)(C)CCC4(C)C)c(-c2ccccc2)c1 ; CC(C)(C)c1ccc(N2c3oc4cc5c(cc4c3B3c4c(cc6oc7ccccc7c6c42)-c2c(ccc4c2C(C)(C)c2cc6c(cc2-4)C(C)(C)CCC6(C)C)N3c2ccc3c(c2)C(C)(C)CCC3(C)C)C(C)(C)CCC5(C)C)c(-c2ccccc2)c1] 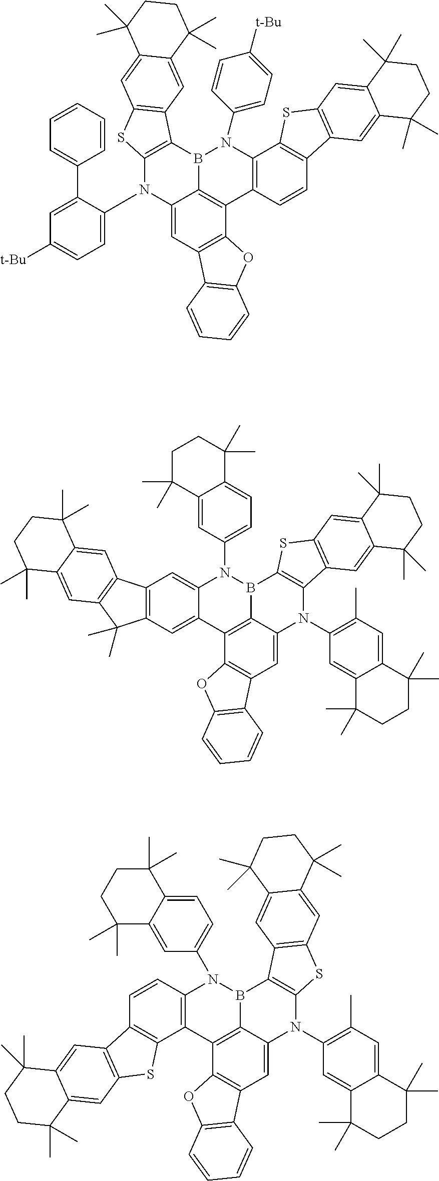 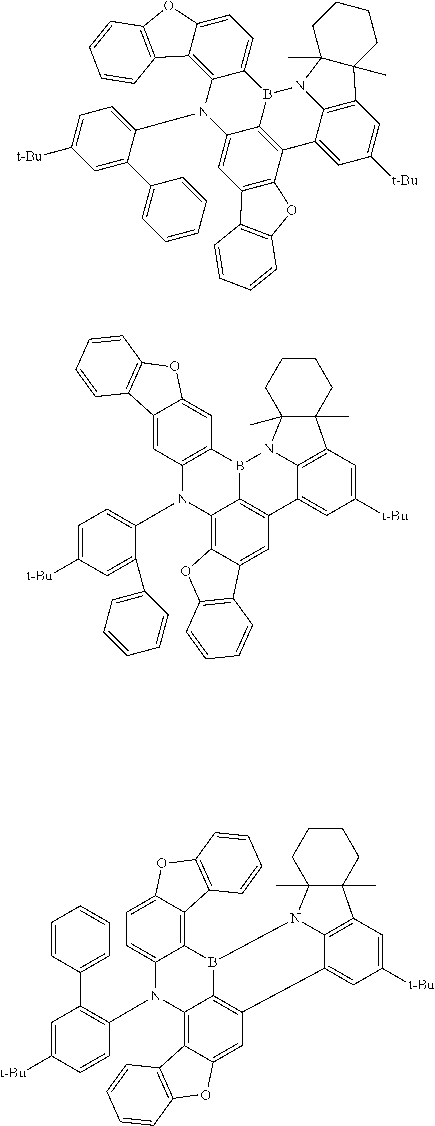 [SMILES: CC(C)(C)c1ccc(N2c3cc4c(oc5ccccc54)c4c3B(c3ccc5oc6ccccc6c5c32)N2c3c-4cc(C(C)(C)C)cc3C3(C)CCCCC23C)c(-c2ccccc2)c1 ; CC(C)(C)c1ccc(N2c3cc4c(cc3B3c5c(cc6c(oc7ccccc76)c52)-c2cc(C(C)(C)C)cc5c2N3C2(C)CCCCC52C)oc2ccccc24)c(-c2ccccc2)c1 ; CC(C)(C)c1ccc(N2c3ccc4oc5ccccc5c4c3B3c4c(cc5oc6ccccc6c5c42)-c2cc(C(C)(C)C)cc4c2N3C2(C)CCCCC42C)c(-c2ccccc2)c1] 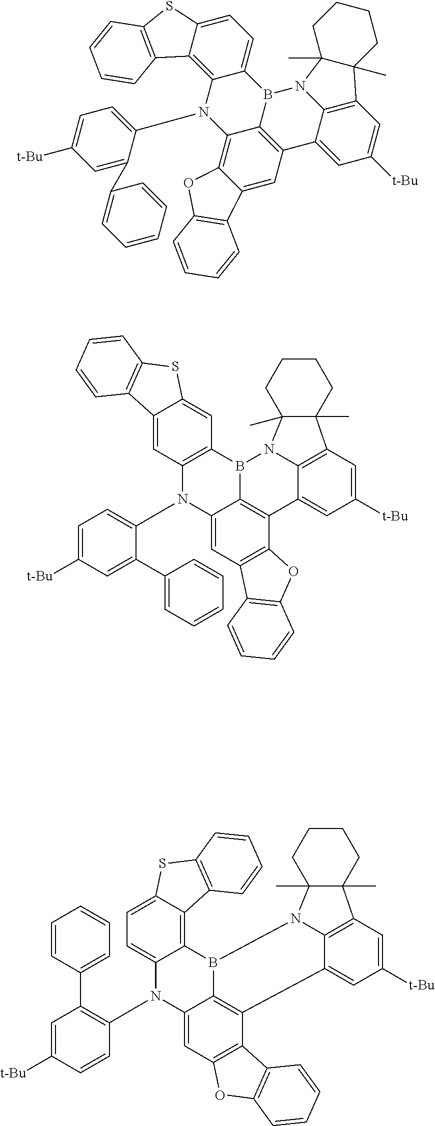 [SMILES: CC(C)(C)c1ccc(N2c3c4c(cc5c3oc3ccccc35)-c3cc(C(C)(C)C)cc5c3N(B4c3ccc4sc6ccccc6c4c32)C2(C)CCCCC52C)c(-c2ccccc2)c1 ; CC(C)(C)c1ccc(N2c3cc4c(cc3B3c5c2cc2c(oc6ccccc62)c5-c2cc(C(C)(C)C)cc5c2N3C2(C)CCCCC52C)sc2ccccc24)c(-c2ccccc2)c1 ; CC(C)(C)c1ccc(N2c3cc4oc5ccccc5c4c4c3B(c3c2ccc2sc5ccccc5c32)N2c3c-4cc(C(C)(C)C)cc3C3(C)CCCCC23C)c(-c2ccccc2)c1] 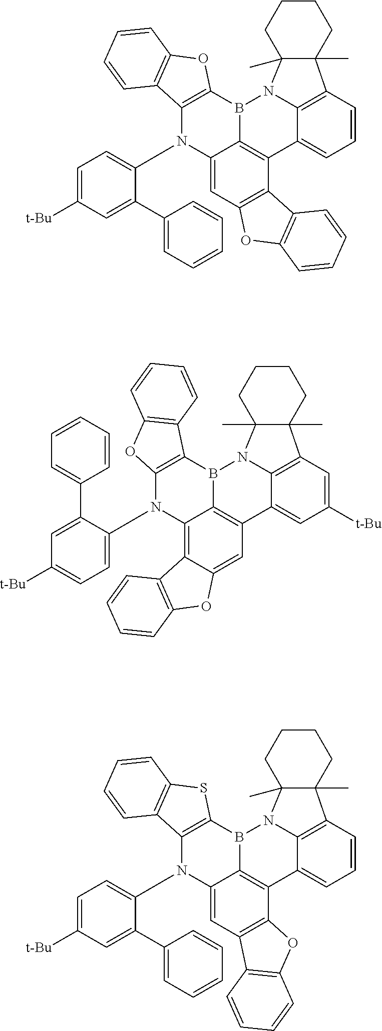 [SMILES: CC(C)(C)c1ccc(N2c3cc4oc5ccccc5c4c4c3B(c3oc5ccccc5c32)N2c3c-4cccc3C3(C)CCCCC23C)c(-c2ccccc2)c1 ; CC(C)(C)c1ccc(N2c3oc4ccccc4c3B3c4c(cc5oc6ccccc6c5c42)-c2cc(C(C)(C)C)cc4c2N3C2(C)CCCCC42C)c(-c2ccccc2)c1 ; CC(C)(C)c1ccc(N2c3cc4c(oc5ccccc54)c4c3B(c3sc5ccccc5c32)N2c3c-4cccc3C3(C)CCCCC23C)c(-c2ccccc2)c1] 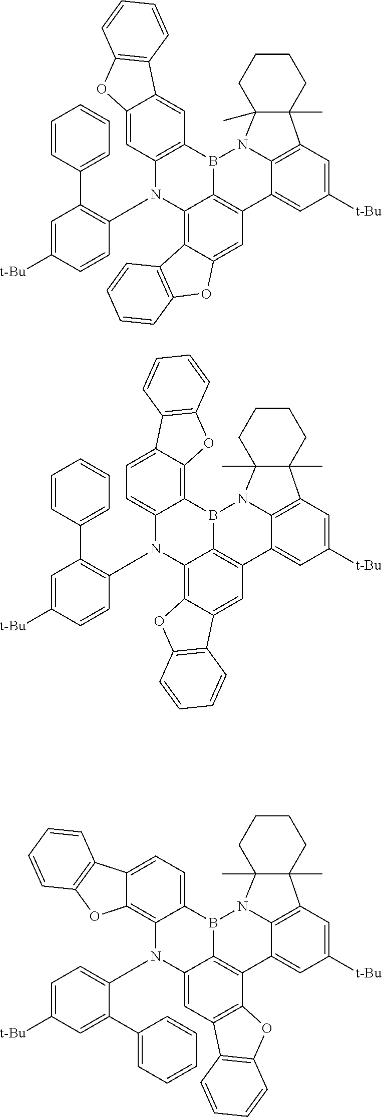 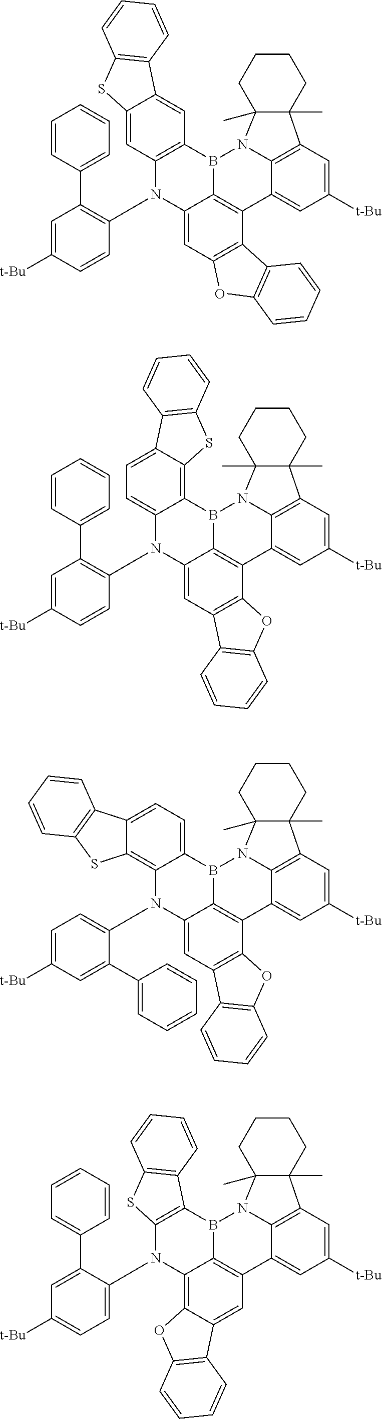 [SMILES: CC(C)(C)c1ccc(N2c3cc4sc5ccccc5c4cc3B3c4c2cc2oc5ccccc5c2c4-c2cc(C(C)(C)C)cc4c2N3C2(C)CCCCC42C)c(-c2ccccc2)c1 ; CC(C)(C)c1ccc(N2c3cc4c(oc5ccccc54)c4c3B(c3c2ccc2c3sc3ccccc32)N2c3c-4cc(C(C)(C)C)cc3C3(C)CCCCC23C)c(-c2ccccc2)c1 ; CC(C)(C)c1ccc(N2c3cc4c(oc5ccccc54)c4c3B(c3ccc5c(sc6ccccc65)c32)N2c3c-4cc(C(C)(C)C)cc3C3(C)CCCCC23C)c(-c2ccccc2)c1 ; CC(C)(C)c1ccc(N2c3sc4ccccc4c3B3c4c(cc5c(oc6ccccc65)c42)-c2cc(C(C)(C)C)cc4c2N3C2(C)CCCCC42C)c(-c2ccccc2)c1] 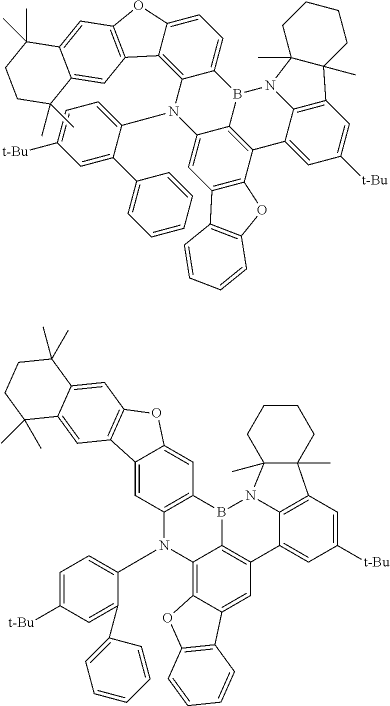 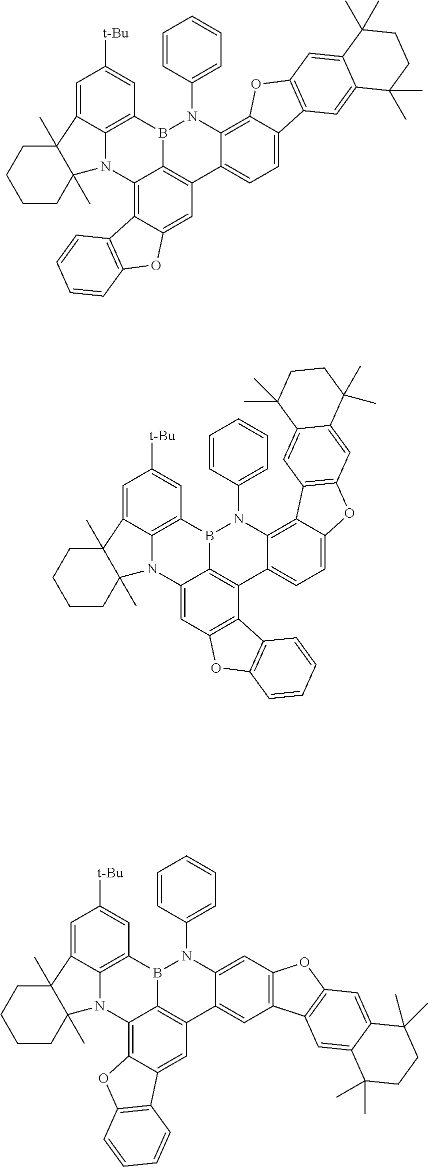 [SMILES: CC(C)(C)c1cc2c3c(c1)C1(C)CCCCC1(C)N3c1c3c(cc4oc5ccccc5c14)-c1ccc4c(oc5cc6c(cc54)C(C)(C)CCC6(C)C)c1N(c1ccccc1)B23 ; CC(C)(C)c1cc2c3c(c1)C1(C)CCCCC1(C)N3c1cc3oc4ccccc4c3c3c1B2N(c1ccccc1)c1c-3ccc2oc3cc4c(cc3c12)C(C)(C)CCC4(C)C ; CC(C)(C)c1cc2c3c(c1)C1(C)CCCCC1(C)N3c1c3c(cc4c1oc1ccccc14)-c1cc4c(cc1N(c1ccccc1)B23)oc1cc2c(cc14)C(C)(C)CCC2(C)C] 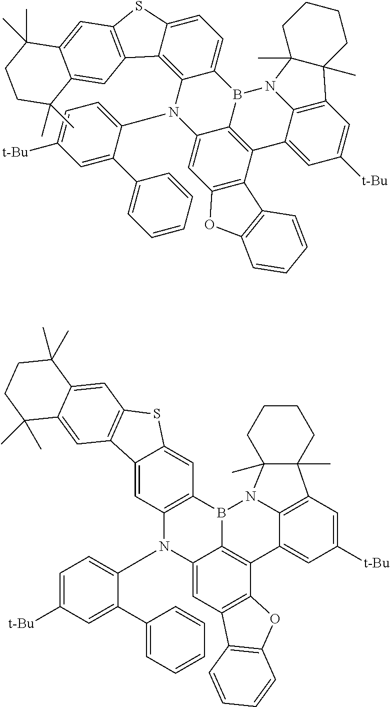 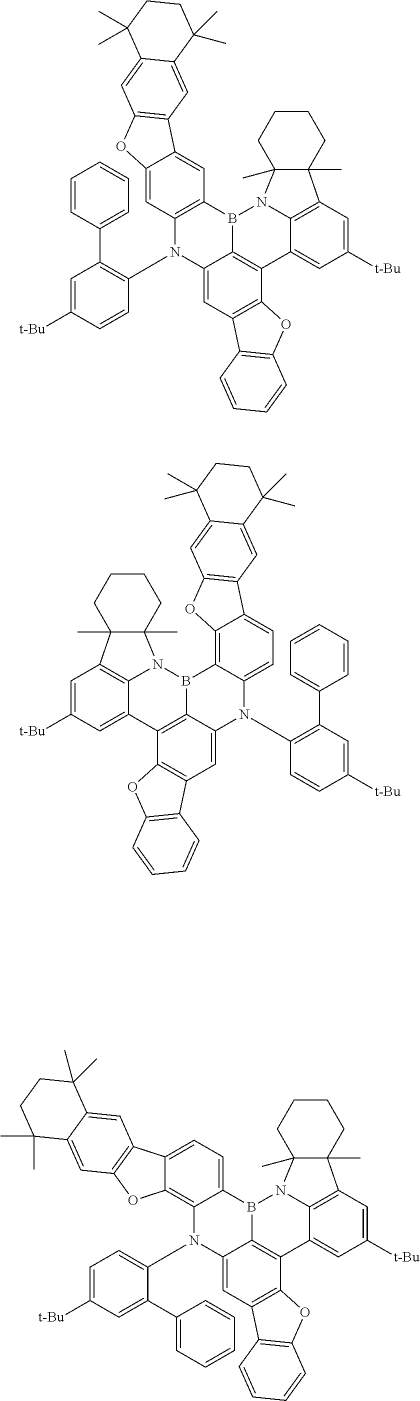 [SMILES: CC(C)(C)c1ccc(N2c3cc4oc5cc6c(cc5c4cc3B3c4c2cc2c(oc5ccccc52)c4-c2cc(C(C)(C)C)cc4c2N3C2(C)CCCCC42C)C(C)(C)CCC6(C)C)c(-c2ccccc2)c1 ; CC(C)(C)c1ccc(N2c3cc4c(oc5ccccc54)c4c3B(c3c2ccc2c3oc3cc5c(cc32)C(C)(C)CCC5(C)C)N2c3c-4cc(C(C)(C)C)cc3C3(C)CCCCC23C)c(-c2ccccc2)c1 ; CC(C)(C)c1ccc(N2c3cc4c(oc5ccccc54)c4c3B(c3ccc5c(oc6cc7c(cc65)C(C)(C)CCC7(C)C)c32)N2c3c-4cc(C(C)(C)C)cc3C3(C)CCCCC23C)c(-c2ccccc2)c1] 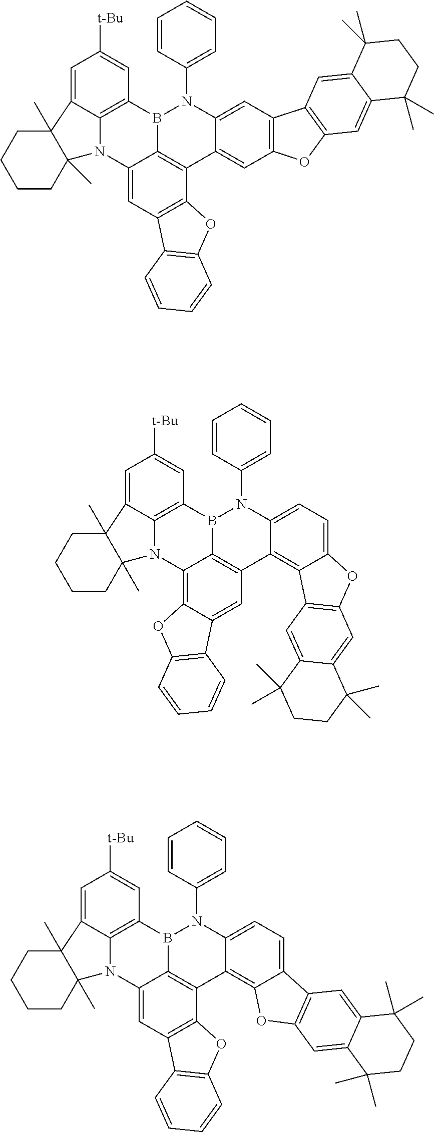 [SMILES: CC(C)(C)c1cc2c3c(c1)C1(C)CCCCC1(C)N3c1cc3c(oc4ccccc43)c3c1B2N(c1ccccc1)c1cc2c(cc1-3)oc1cc3c(cc12)C(C)(C)CCC3(C)C ; CC(C)(C)c1cc2c3c(c1)C1(C)CCCCC1(C)N3c1c3c(cc4c1oc1ccccc14)-c1c(ccc4oc5cc6c(cc5c14)C(C)(C)CCC6(C)C)N(c1ccccc1)B23 ; CC(C)(C)c1cc2c3c(c1)C1(C)CCCCC1(C)N3c1cc3c(oc4ccccc43)c3c1B2N(c1ccccc1)c1ccc2c(oc4cc5c(cc42)C(C)(C)CCC5(C)C)c1-3] 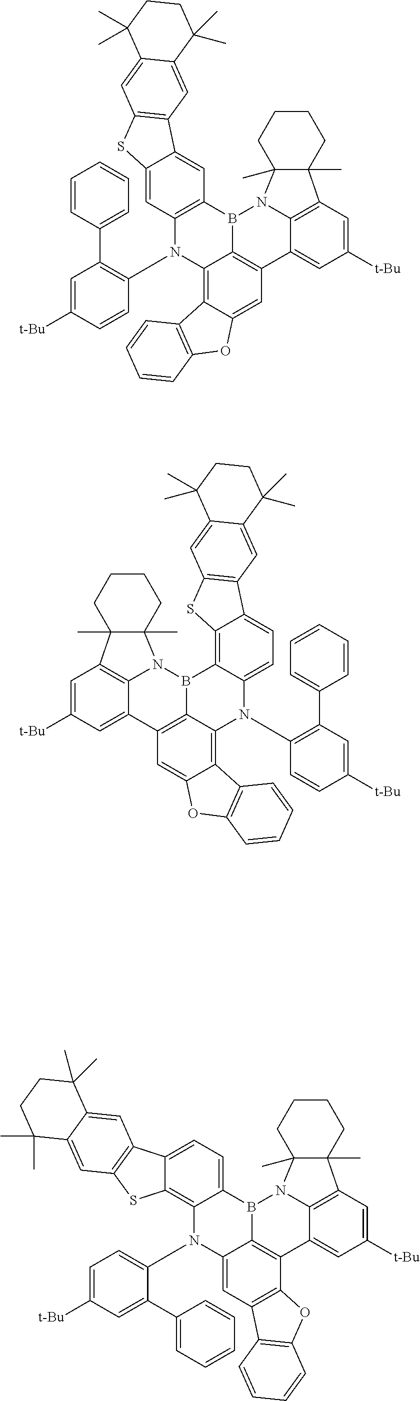 [SMILES: CC(C)(C)c1ccc(N2c3cc4sc5cc6c(cc5c4cc3B3c4c(cc5oc7ccccc7c5c42)-c2cc(C(C)(C)C)cc4c2N3C2(C)CCCCC42C)C(C)(C)CCC6(C)C)c(-c2ccccc2)c1 ; CC(C)(C)c1ccc(N2c3ccc4c(sc5cc6c(cc54)C(C)(C)CCC6(C)C)c3B3c4c(cc5oc6ccccc6c5c42)-c2cc(C(C)(C)C)cc4c2N3C2(C)CCCCC42C)c(-c2ccccc2)c1 ; CC(C)(C)c1ccc(N2c3cc4c(oc5ccccc54)c4c3B(c3ccc5c(sc6cc7c(cc65)C(C)(C)CCC7(C)C)c32)N2c3c-4cc(C(C)(C)C)cc3C3(C)CCCCC23C)c(-c2ccccc2)c1] 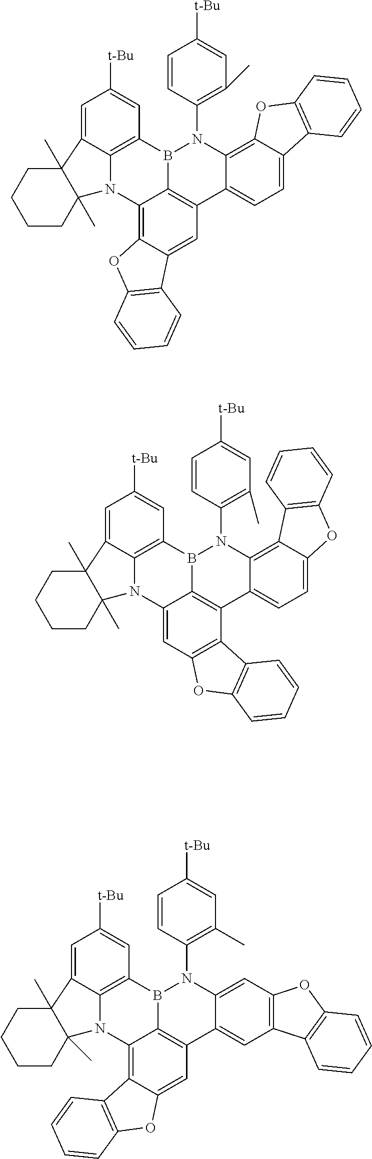 [SMILES: Cc1cc(C(C)(C)C)ccc1N1B2c3cc(C(C)(C)C)cc4c3N(c3c2c(cc2c3oc3ccccc32)-c2ccc3c(oc5ccccc53)c21)C1(C)CCCCC41C ; Cc1cc(C(C)(C)C)ccc1N1B2c3cc(C(C)(C)C)cc4c3N(c3cc5oc6ccccc6c5c(c32)-c2ccc3oc5ccccc5c3c21)C1(C)CCCCC41C ; Cc1cc(C(C)(C)C)ccc1N1B2c3cc(C(C)(C)C)cc4c3N(c3c2c(cc2oc5ccccc5c32)-c2cc3c(cc21)oc1ccccc13)C1(C)CCCCC41C] 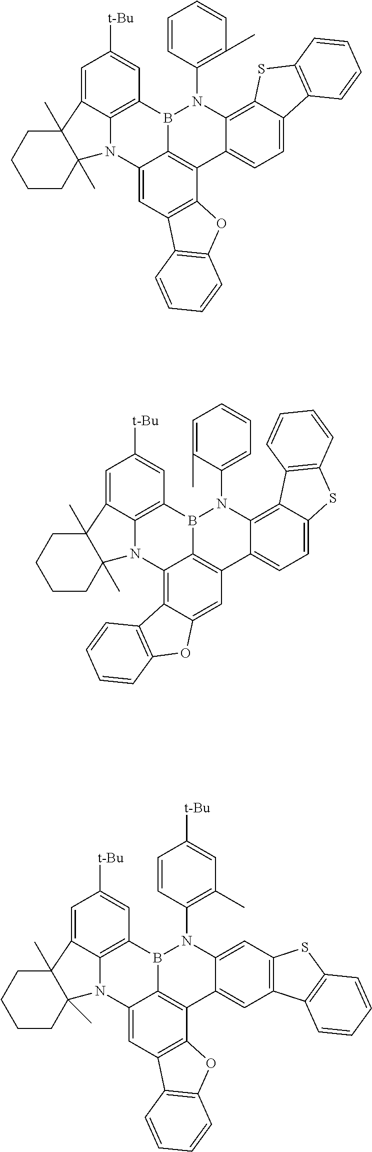 [SMILES: Cc1ccccc1N1B2c3cc(C(C)(C)C)cc4c3N(c3cc5c(oc6ccccc65)c(c32)-c2ccc3c(sc5ccccc53)c21)C1(C)CCCCC41C ; Cc1ccccc1N1B2c3cc(C(C)(C)C)cc4c3N(c3c2c(cc2oc5ccccc5c32)-c2ccc3sc5ccccc5c3c21)C1(C)CCCCC41C ; Cc1cc(C(C)(C)C)ccc1N1B2c3cc(C(C)(C)C)cc4c3N(c3cc5c(oc6ccccc65)c(c32)-c2cc3c(cc21)sc1ccccc13)C1(C)CCCCC41C] 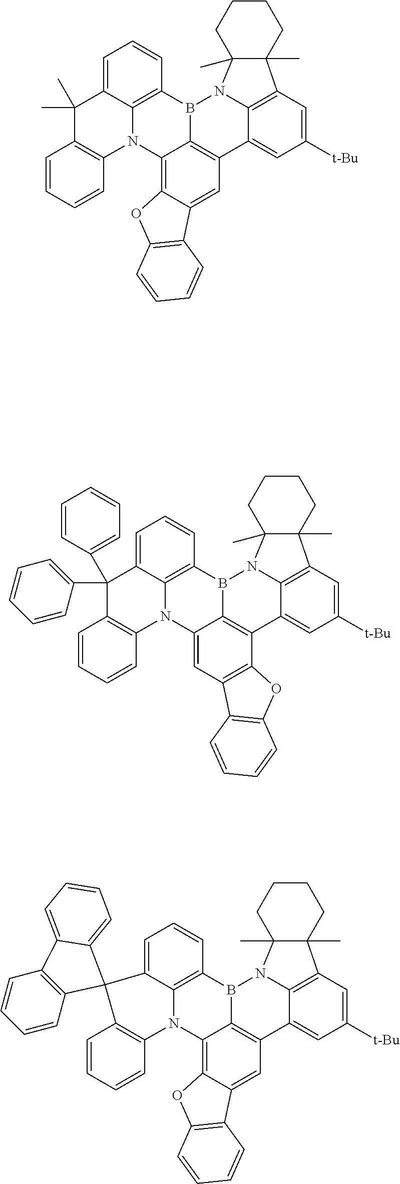 [SMILES: CC(C)(C)c1cc2c3c(c1)C1(C)CCCCC1(C)N3B1c3cccc4c3N(c3ccccc3C4(C)C)c3c1c-2cc1c3oc2ccccc21 ; CC(C)(C)c1cc2c3c(c1)C1(C)CCCCC1(C)N3B1c3cccc4c3N(c3ccccc3C4(c3ccccc3)c3ccccc3)c3cc4c(oc5ccccc54)c-2c31 ; CC(C)(C)c1cc2c3c(c1)C1(C)CCCCC1(C)N3B1c3cccc4c3N(c3ccccc3C43c4ccccc4-c4ccccc43)c3c1c-2cc1c3oc2ccccc21] 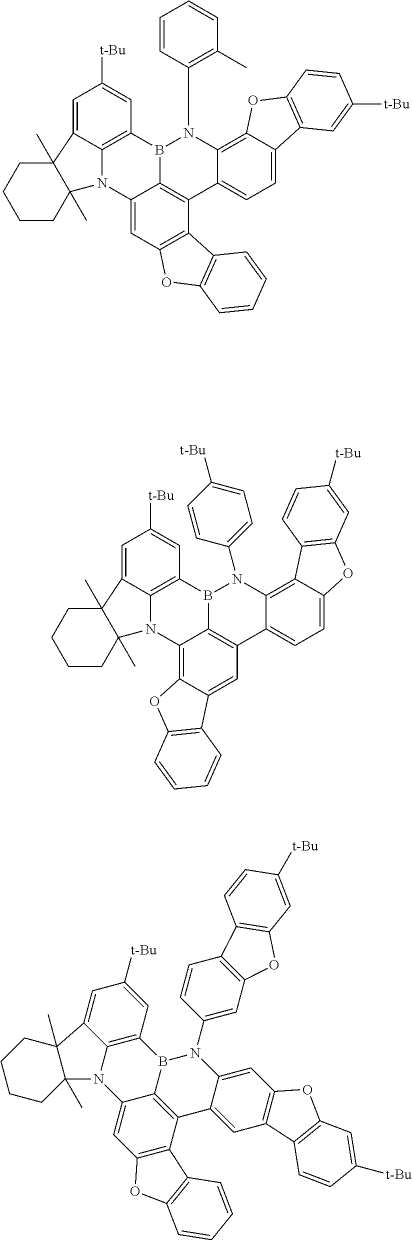 [SMILES: Cc1ccccc1N1B2c3cc(C(C)(C)C)cc4c3N(c3cc5oc6ccccc6c5c(c32)-c2ccc3c(oc5ccc(C(C)(C)C)cc53)c21)C1(C)CCCCC41C ; CC(C)(C)c1ccc(N2B3c4cc(C(C)(C)C)cc5c4N(c4c3c(cc3c4oc4ccccc43)-c3ccc4oc6cc(C(C)(C)C)ccc6c4c32)C2(C)CCCCC52C)cc1 ; CC(C)(C)c1cc2c3c(c1)C1(C)CCCCC1(C)N3c1cc3oc4ccccc4c3c3c1B2N(c1ccc2c(c1)oc1cc(C(C)(C)C)ccc12)c1cc2oc4cc(C(C)(C)C)ccc4c2cc1-3] 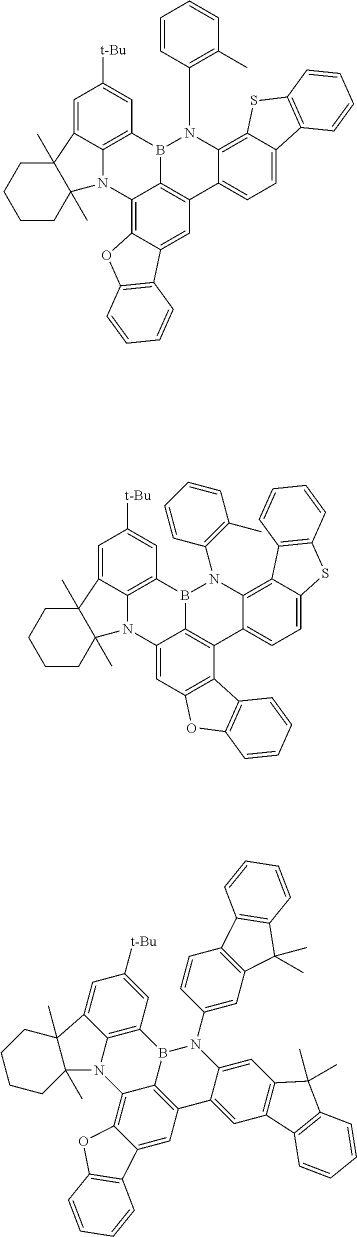 [SMILES: Cc1ccccc1N1B2c3cc(C(C)(C)C)cc4c3N(c3c2c(cc2c3oc3ccccc32)-c2ccc3c(sc5ccccc53)c21)C1(C)CCCCC41C ; Cc1ccccc1N1B2c3cc(C(C)(C)C)cc4c3N(c3cc5oc6ccccc6c5c(c32)-c2ccc3sc5ccccc5c3c21)C1(C)CCCCC41C ; CC(C)(C)c1cc2c3c(c1)C1(C)CCCCC1(C)N3c1c3c(cc4c1oc1ccccc14)-c1cc4c(cc1N(c1ccc5c(c1)C(C)(C)c1ccccc1-5)B23)C(C)(C)c1ccccc1-4] 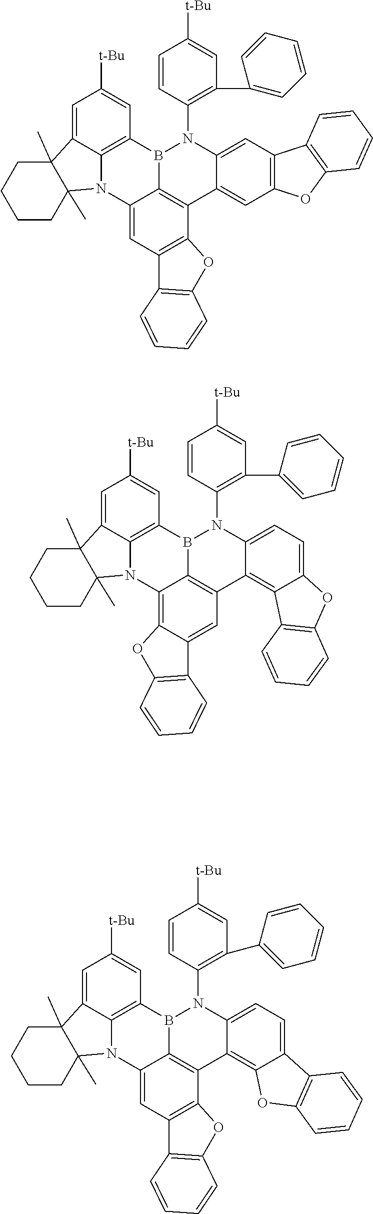 [SMILES: CC(C)(C)c1ccc(N2B3c4cc(C(C)(C)C)cc5c4N(c4cc6c(oc7ccccc76)c(c43)-c3cc4oc6ccccc6c4cc32)C2(C)CCCCC52C)c(-c2ccccc2)c1 ; CC(C)(C)c1ccc(N2B3c4cc(C(C)(C)C)cc5c4N(c4c3c(cc3c4oc4ccccc43)-c3c2ccc2oc4ccccc4c32)C2(C)CCCCC52C)c(-c2ccccc2)c1 ; CC(C)(C)c1ccc(N2B3c4cc(C(C)(C)C)cc5c4N(c4cc6c(oc7ccccc76)c(c43)-c3c2ccc2c3oc3ccccc32)C2(C)CCCCC52C)c(-c2ccccc2)c1] 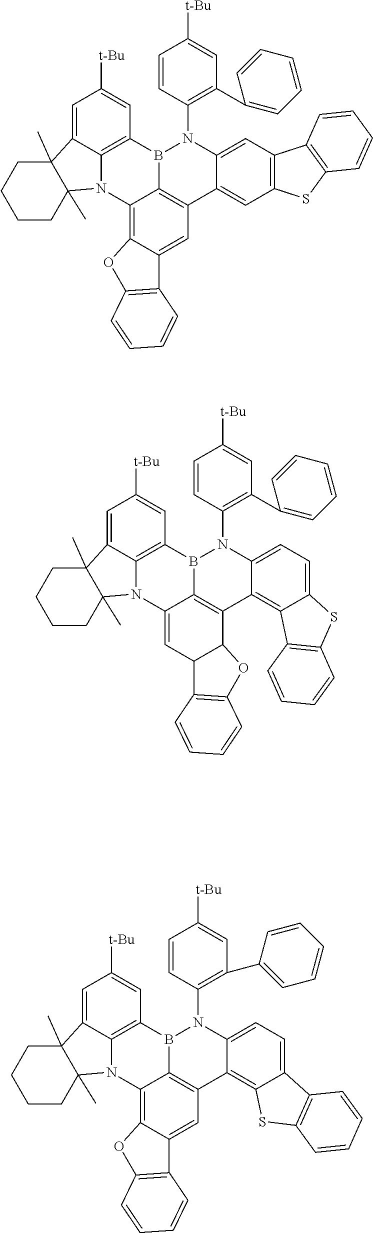 [SMILES: CC(C)(C)c1ccc(N2B3c4cc(C(C)(C)C)cc5c4N(c4c3c(cc3c4oc4ccccc43)-c3cc4sc6ccccc6c4cc32)C2(C)CCCCC52C)c(-c2ccccc2)c1 ; CC(C)(C)c1ccc(N2B3C4=C(c5c2ccc2sc6ccccc6c52)C2Oc5ccccc5C2C=C4N2c4c3cc(C(C)(C)C)cc4C3(C)CCCCC23C)c(-c2ccccc2)c1 ; CC(C)(C)c1ccc(N2B3c4cc(C(C)(C)C)cc5c4N(c4c3c(cc3c4oc4ccccc43)-c3c2ccc2c3sc3ccccc32)C2(C)CCCCC52C)c(-c2ccccc2)c1] 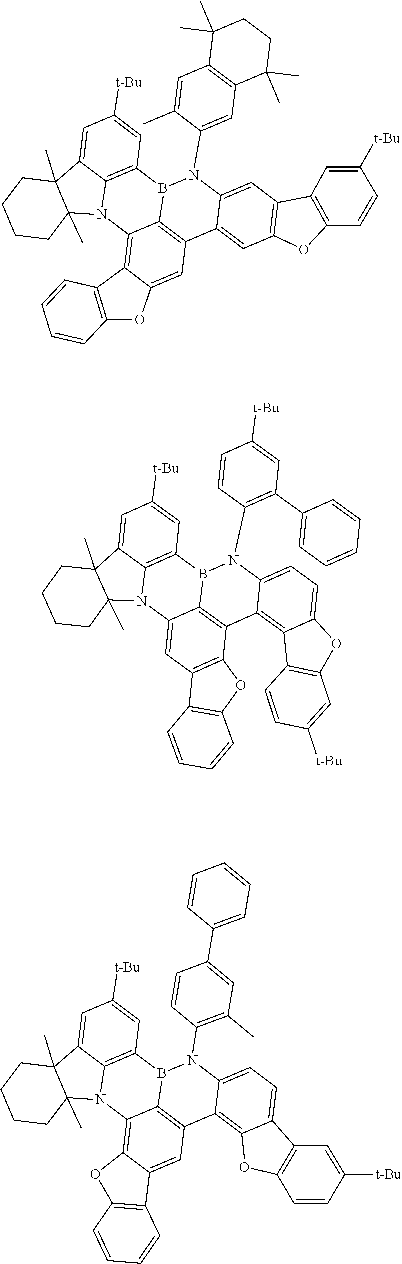 [SMILES: Cc1cc2c(cc1N1B3c4cc(C(C)(C)C)cc5c4N(c4c3c(cc3oc6ccccc6c43)-c3cc4oc6ccc(C(C)(C)C)cc6c4cc31)C1(C)CCCCC51C)C(C)(C)CCC2(C)C ; CC(C)(C)c1ccc(N2B3c4cc(C(C)(C)C)cc5c4N(c4cc6c(oc7ccccc76)c(c43)-c3c2ccc2oc4cc(C(C)(C)C)ccc4c32)C2(C)CCCCC52C)c(-c2ccccc2)c1 ; Cc1cc(-c2ccccc2)ccc1N1B2c3cc(C(C)(C)C)cc4c3N(c3c2c(cc2c3oc3ccccc32)-c2c1ccc1c2oc2ccc(C(C)(C)C)cc21)C1(C)CCCCC41C] 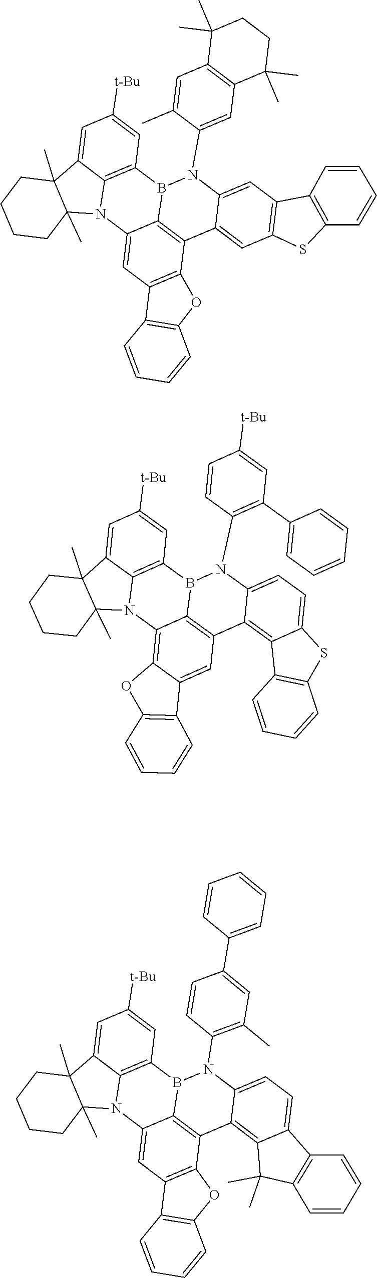 [SMILES: Cc1cc2c(cc1N1B3c4cc(C(C)(C)C)cc5c4N(c4cc6c(oc7ccccc76)c(c43)-c3cc4sc6ccccc6c4cc31)C1(C)CCCCC51C)C(C)(C)CCC2(C)C ; CC(C)(C)c1ccc(N2B3c4cc(C(C)(C)C)cc5c4N(c4c3c(cc3c4oc4ccccc43)-c3c2ccc2sc4ccccc4c32)C2(C)CCCCC52C)c(-c2ccccc2)c1 ; Cc1cc(-c2ccccc2)ccc1N1B2c3cc(C(C)(C)C)cc4c3N(c3cc5c(oc6ccccc65)c(c32)-c2c1ccc1c2C(C)(C)c2ccccc2-1)C1(C)CCCCC41C] 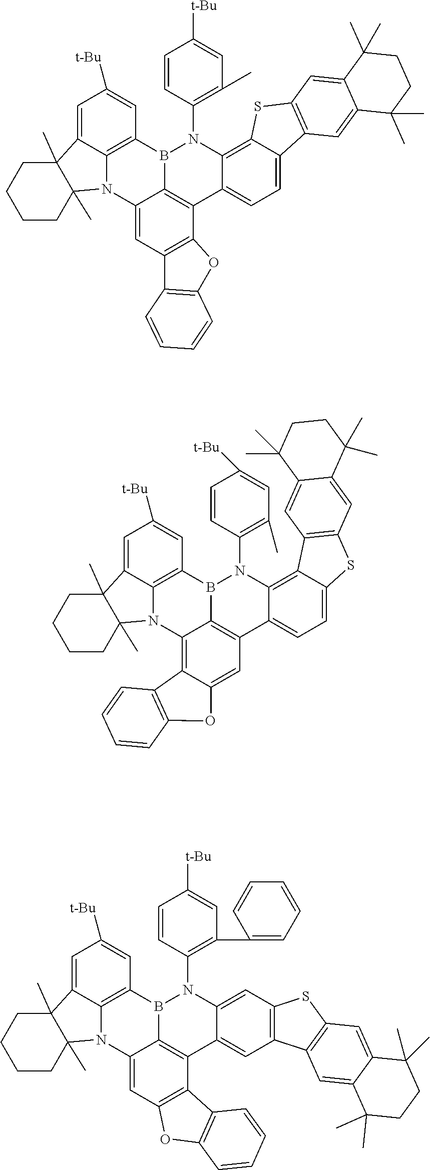 [SMILES: Cc1cc(C(C)(C)C)ccc1N1B2c3cc(C(C)(C)C)cc4c3N(c3cc5c(oc6ccccc65)c(c32)-c2ccc3c(sc5cc6c(cc53)C(C)(C)CCC6(C)C)c21)C1(C)CCCCC41C ; Cc1cc(C(C)(C)C)ccc1N1B2c3cc(C(C)(C)C)cc4c3N(c3c2c(cc2oc5ccccc5c32)-c2ccc3sc5cc6c(cc5c3c21)C(C)(C)CCC6(C)C)C1(C)CCCCC41C ; CC(C)(C)c1ccc(N2B3c4cc(C(C)(C)C)cc5c4N(c4cc6oc7ccccc7c6c(c43)-c3cc4c(cc32)sc2cc3c(cc24)C(C)(C)CCC3(C)C)C2(C)CCCCC52C)c(-c2ccccc2)c1] 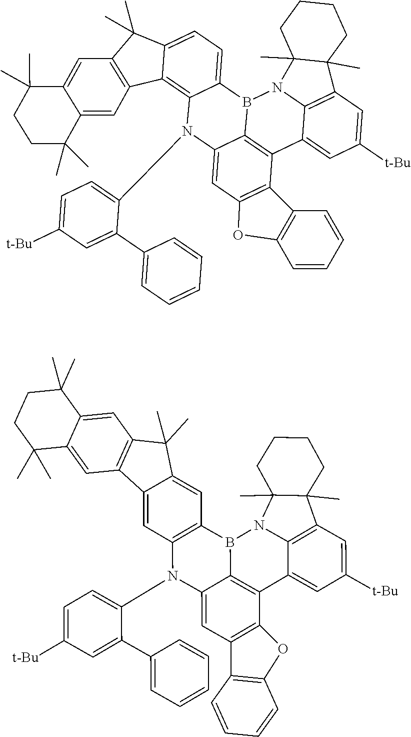 [SMILES: CC(C)(C)c1ccc(N2c3cc4oc5ccccc5c4c4c3B(c3ccc5c(c32)-c2cc3c(cc2C5(C)C)C(C)(C)CCC3(C)C)N2c3c-4cc(C(C)(C)C)cc3C3(C)CCCCC23C)c(-c2ccccc2)c1 ; CC(C)(C)c1ccc(N2c3cc4c(cc3B3c5c2cc2c(oc6ccccc62)c5-c2cc(C(C)(C)C)cc5c2N3C2(C)CCCCC52C)C(C)(C)c2cc3c(cc2-4)C(C)(C)CCC3(C)C)c(-c2ccccc2)c1] 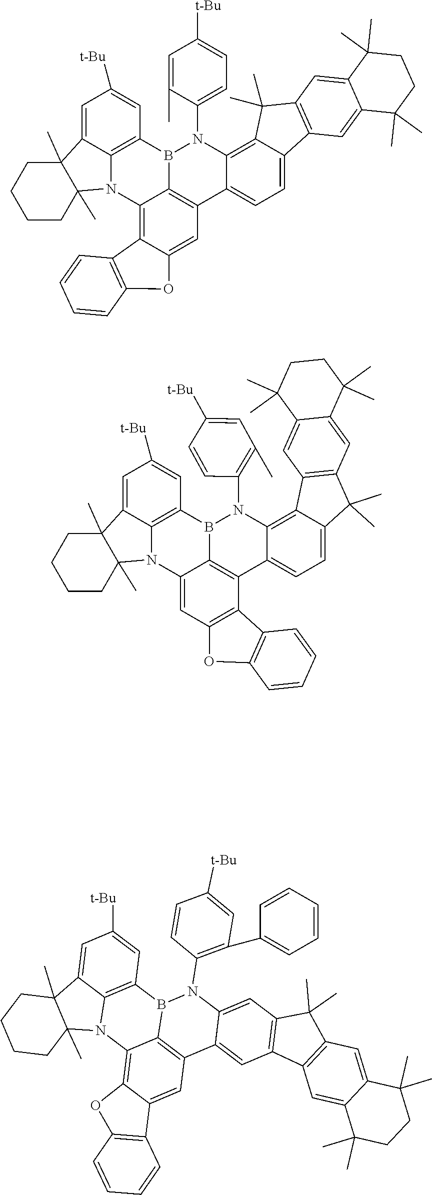 [SMILES: Cc1cc(C(C)(C)C)ccc1N1B2c3cc(C(C)(C)C)cc4c3N(c3c2c(cc2oc5ccccc5c32)-c2ccc3c(c21)C(C)(C)c1cc2c(cc1-3)C(C)(C)CCC2(C)C)C1(C)CCCCC41C ; Cc1cc(C(C)(C)C)ccc1N1B2c3cc(C(C)(C)C)cc4c3N(c3cc5oc6ccccc6c5c(c32)-c2ccc3c(c21)-c1cc2c(cc1C3(C)C)C(C)(C)CCC2(C)C)C1(C)CCCCC41C ; CC(C)(C)c1ccc(N2B3c4cc(C(C)(C)C)cc5c4N(c4c3c(cc3c4oc4ccccc43)-c3cc4c(cc32)C(C)(C)c2cc3c(cc2-4)C(C)(C)CCC3(C)C)C2(C)CCCCC52C)c(-c2ccccc2)c1] 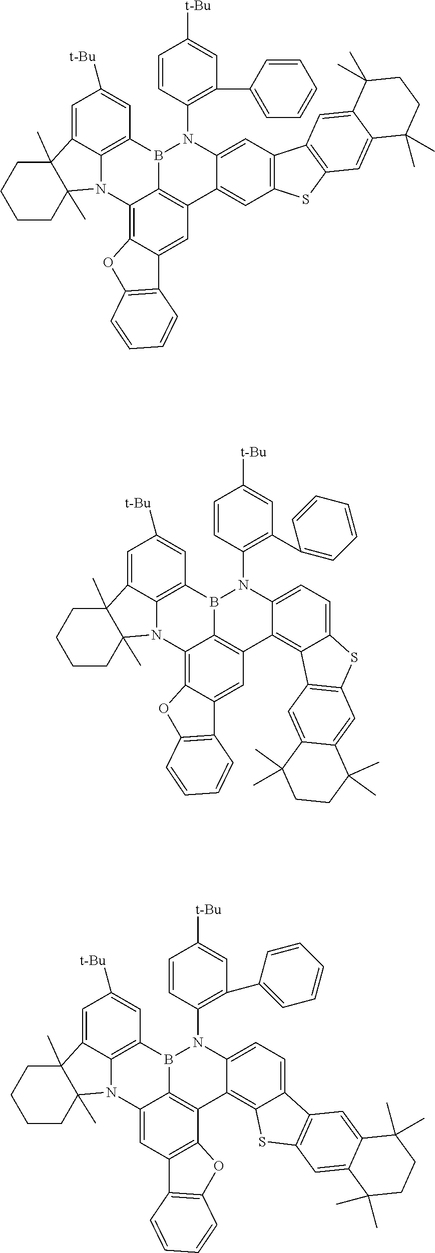 [SMILES: CC(C)(C)c1ccc(N2B3c4cc(C(C)(C)C)cc5c4N(c4c3c(cc3c4oc4ccccc43)-c3cc4sc6cc7c(cc6c4cc32)C(C)(C)CCC7(C)C)C2(C)CCCCC52C)c(-c2ccccc2)c1 ; CC(C)(C)c1ccc(N2B3c4cc(C(C)(C)C)cc5c4N(c4c3c(cc3c4oc4ccccc43)-c3c2ccc2sc4cc6c(cc4c32)C(C)(C)CCC6(C)C)C2(C)CCCCC52C)c(-c2ccccc2)c1 ; CC(C)(C)c1ccc(N2B3c4cc(C(C)(C)C)cc5c4N(c4cc6c(oc7ccccc76)c(c43)-c3c2ccc2c3sc3cc4c(cc32)C(C)(C)CCC4(C)C)C2(C)CCCCC52C)c(-c2ccccc2)c1] 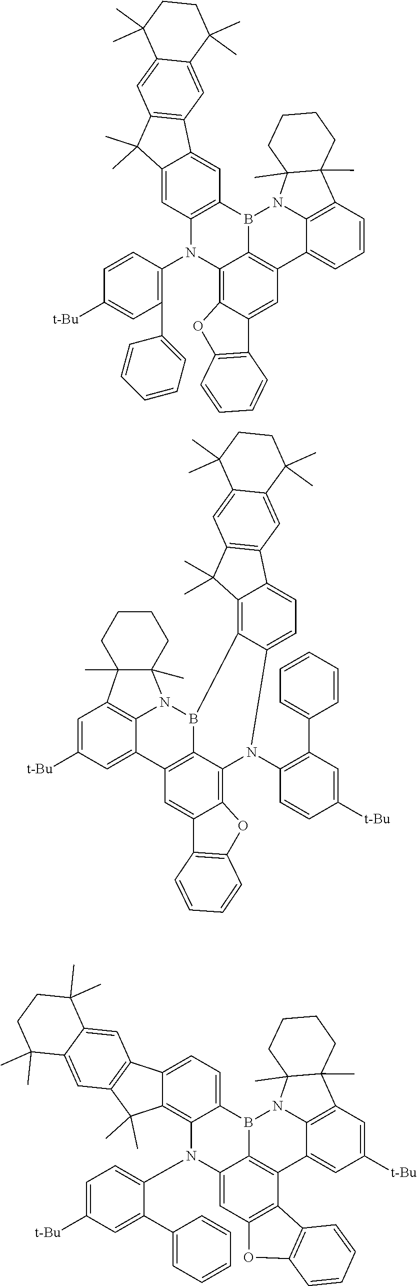 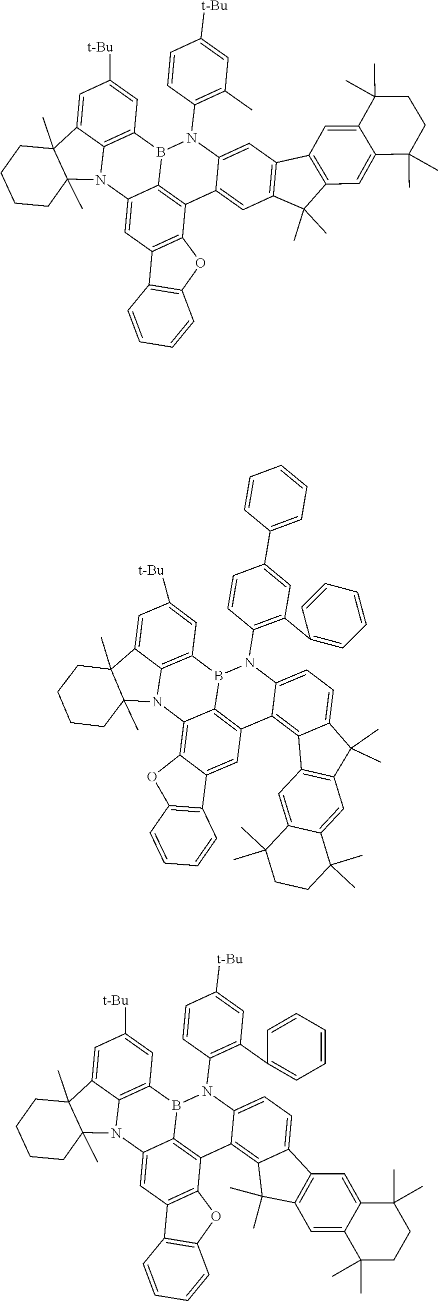 [SMILES: Cc1cc(C(C)(C)C)ccc1N1B2c3cc(C(C)(C)C)cc4c3N(c3cc5c(oc6ccccc65)c(c32)-c2cc3c(cc21)-c1cc2c(cc1C3(C)C)C(C)(C)CCC2(C)C)C1(C)CCCCC41C ; CC(C)(C)c1cc2c3c(c1)C1(C)CCCCC1(C)N3c1c3c(cc4c1oc1ccccc14)-c1c(ccc4c1-c1cc5c(cc1C4(C)C)C(C)(C)CCC5(C)C)N(c1ccc(-c4ccccc4)cc1-c1ccccc1)B23 ; CC(C)(C)c1ccc(N2B3c4cc(C(C)(C)C)cc5c4N(c4cc6c(oc7ccccc76)c(c43)-c3c2ccc2c3C(C)(C)c3cc4c(cc3-2)C(C)(C)CCC4(C)C)C2(C)CCCCC52C)c(-c2ccccc2)c1] 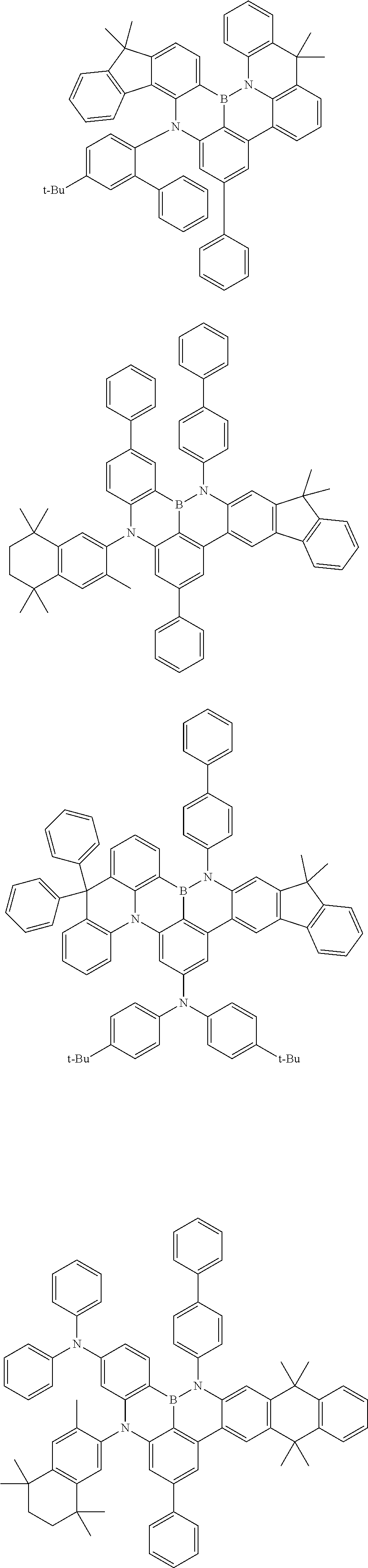 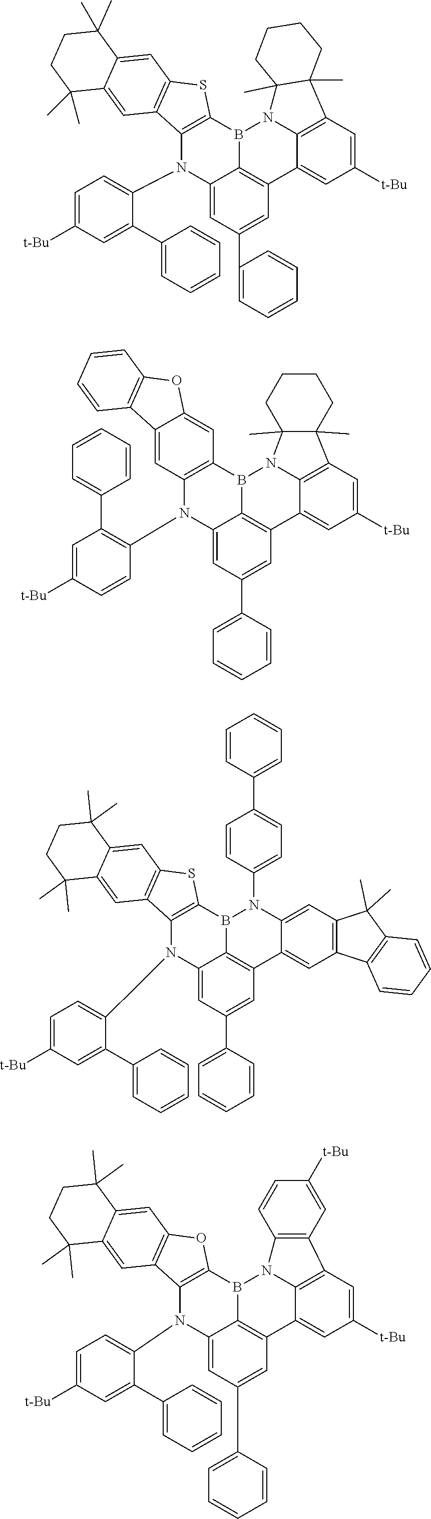 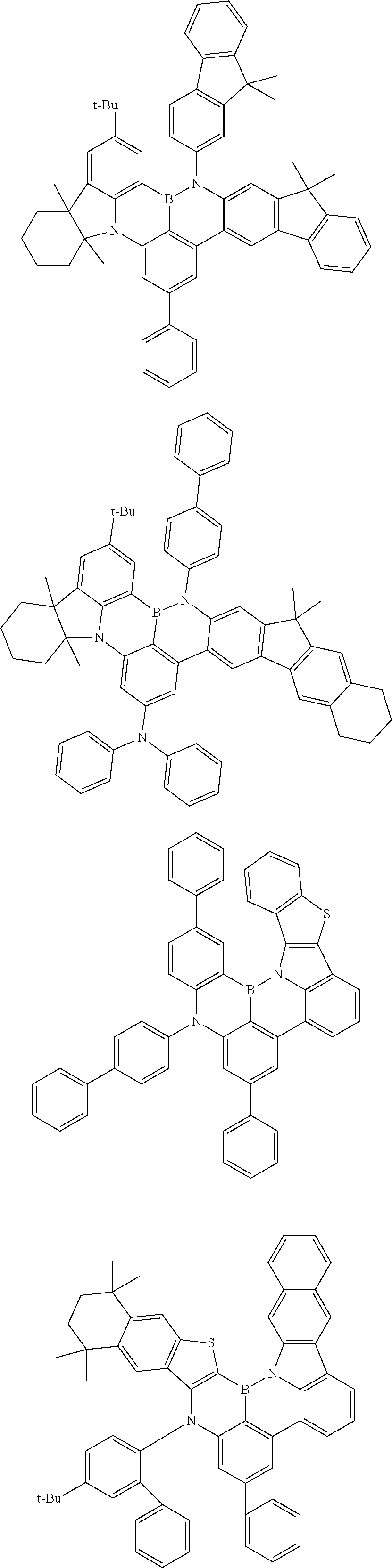 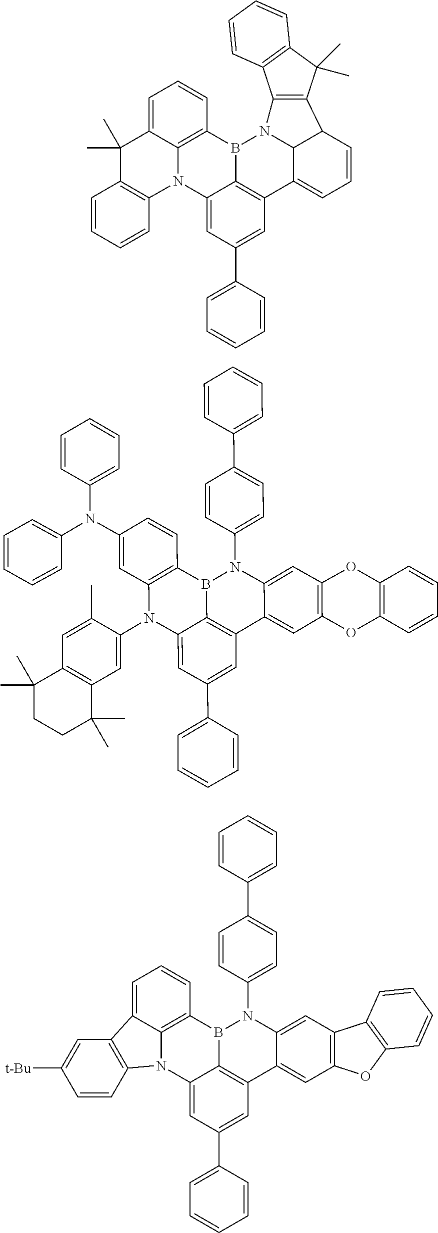 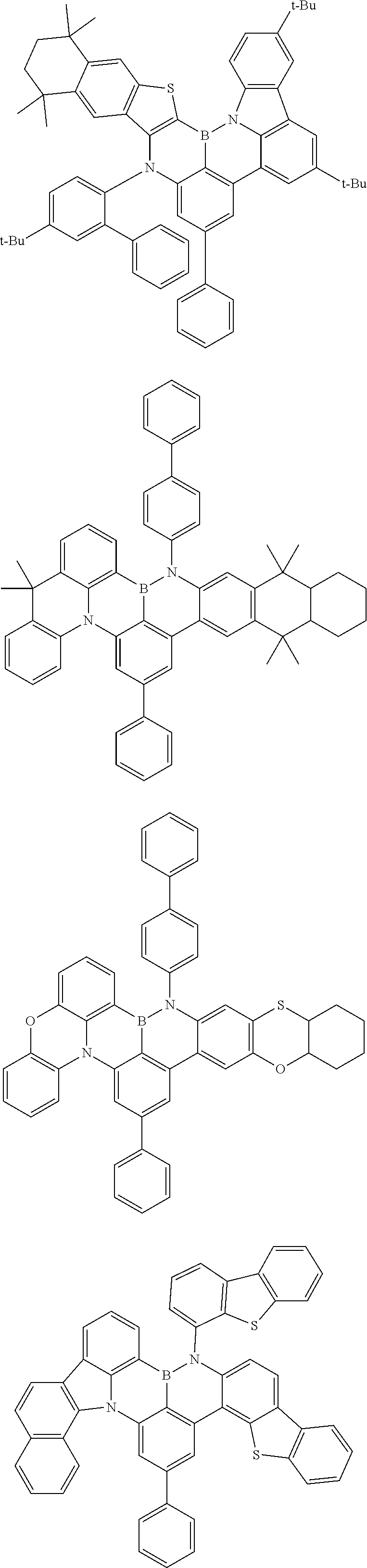 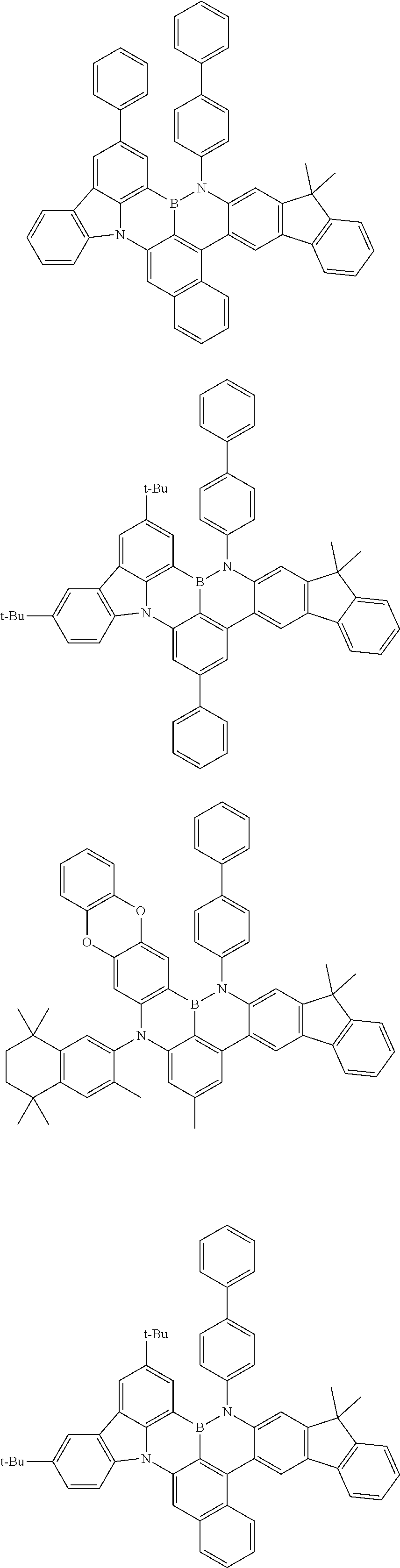 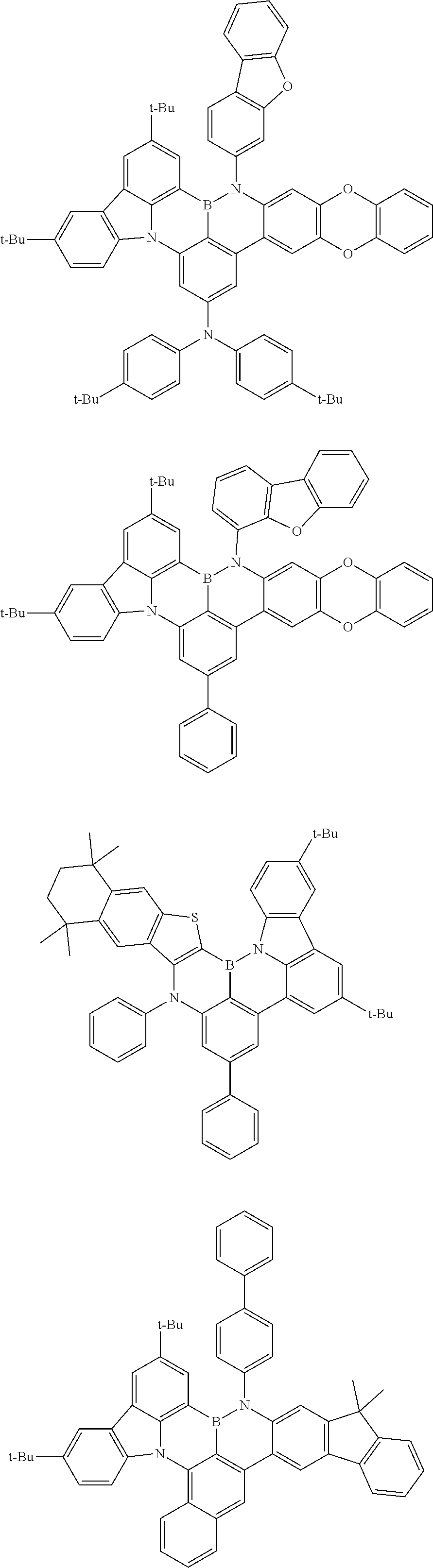 [SMILES: CC(C)(C)c1ccc(N(c2ccc(C(C)(C)C)cc2)c2cc3c4c(c2)-n2c5ccc(C(C)(C)C)cc5c5cc(C(C)(C)C)cc(c52)B4N(c2ccc4c(c2)oc2ccccc24)c2cc4c(cc2-3)Oc2ccccc2O4)cc1 ; CC(C)(C)c1ccc2c(c1)c1cc(C(C)(C)C)cc3c1n2-c1cc(-c2ccccc2)cc2c1B3N(c1cccc3c1oc1ccccc13)c1cc3c(cc1-2)Oc1ccccc1O3 ; CC(C)(C)c1ccc2c(c1)c1cc(C(C)(C)C)cc3c1n2B1c2sc4cc5c(cc4c2N(c2ccccc2)c2cc(-c4ccccc4)cc-3c21)C(C)(C)CCC5(C)C ; CC(C)(C)c1ccc2c(c1)c1cc(C(C)(C)C)cc3c1n2-c1c2c(cc4ccccc14)-c1cc4c(cc1N(c1ccc(-c5ccccc5)cc1)B23)C(C)(C)c1ccccc1-4] 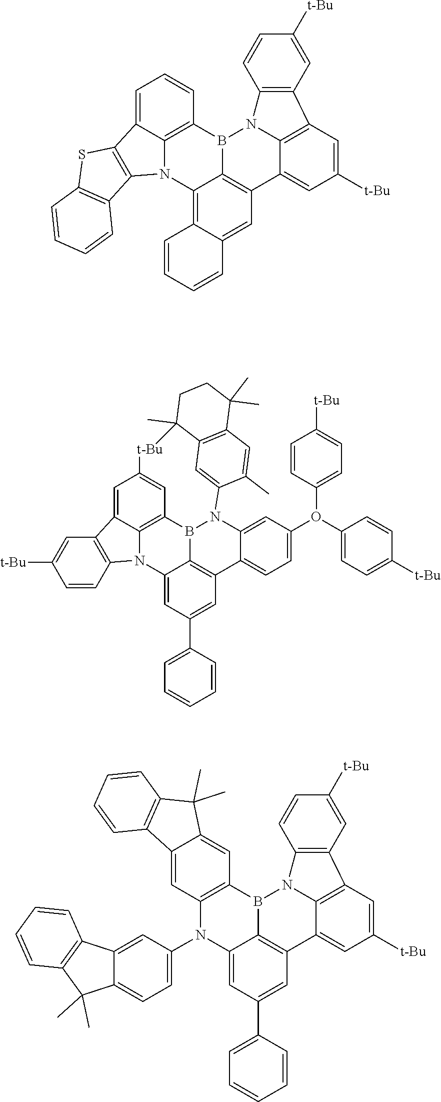 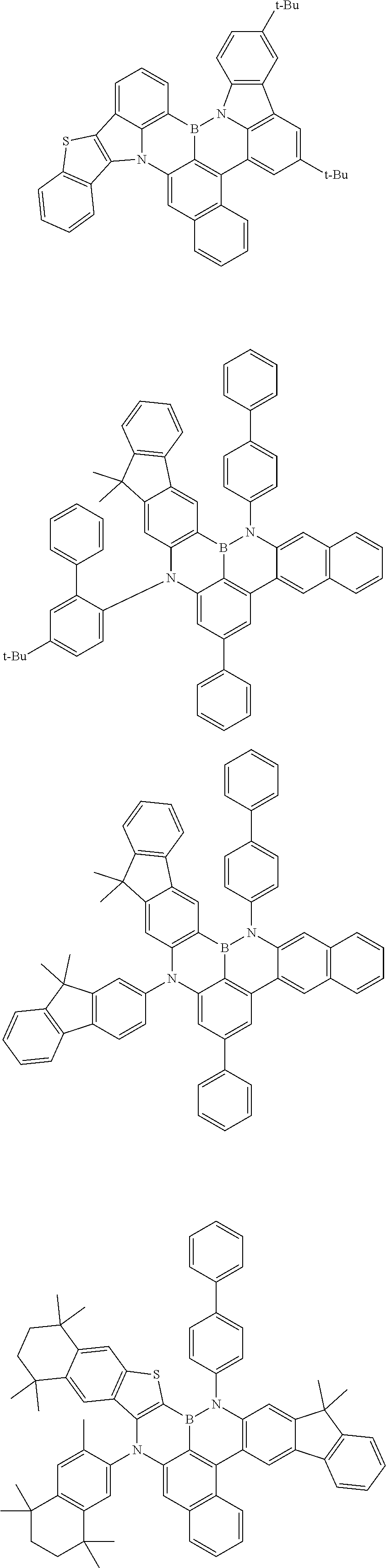 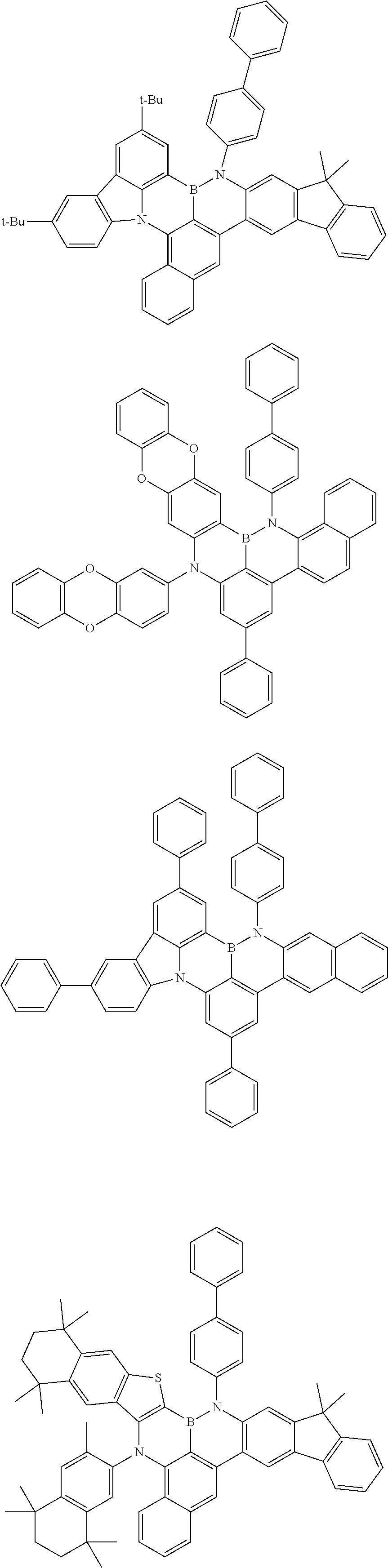 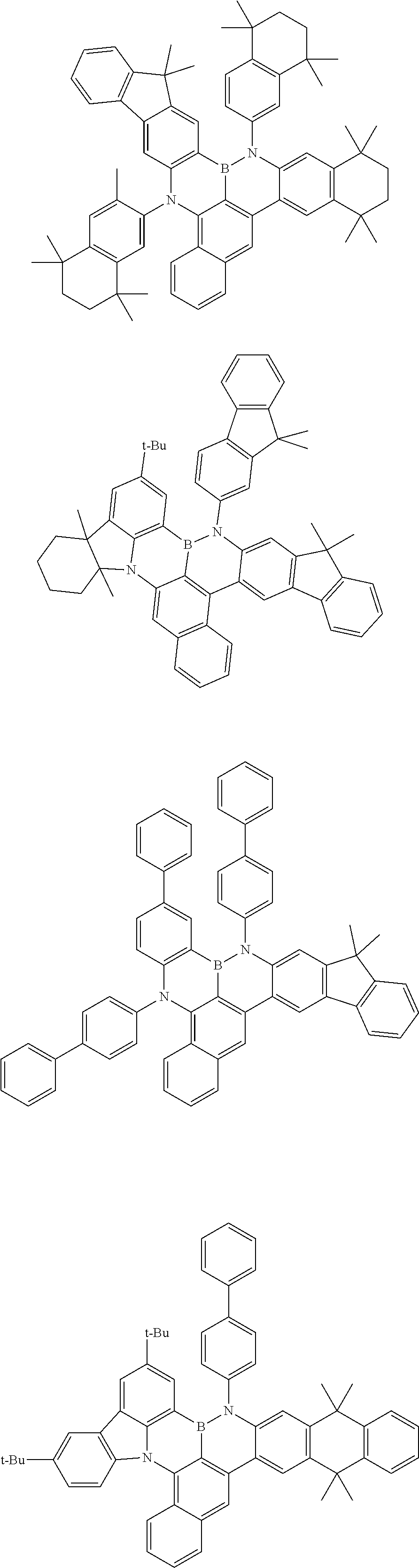 [SMILES: Cc1cc2c(cc1N1c3cc4c(cc3B3c5c(cc6ccccc6c51)-c1cc5c(cc1N3c1ccc3c(c1)C(C)(C)CCC3(C)C)C(C)(C)CCC5(C)C)C(C)(C)c1ccccc1-4)C(C)(C)CCC2(C)C ; CC(C)(C)c1cc2c3c(c1)C1(C)CCCCC1(C)N3c1cc3ccccc3c3c1B2N(c1ccc2c(c1)C(C)(C)c1ccccc1-2)c1cc2c(cc1-3)-c1ccccc1C2(C)C ; CC1(C)c2ccccc2-c2cc3c(cc21)N(c1ccc(-c2ccccc2)cc1)B1c2cc(-c4ccccc4)ccc2N(c2ccc(-c4ccccc4)cc2)c2c1c-3cc1ccccc21 ; CC(C)(C)c1ccc2c(c1)c1cc(C(C)(C)C)cc3c1n2-c1c2c(cc4ccccc14)-c1cc4c(cc1N(c1ccc(-c5ccccc5)cc1)B23)C(C)(C)c1ccccc1C4(C)C] 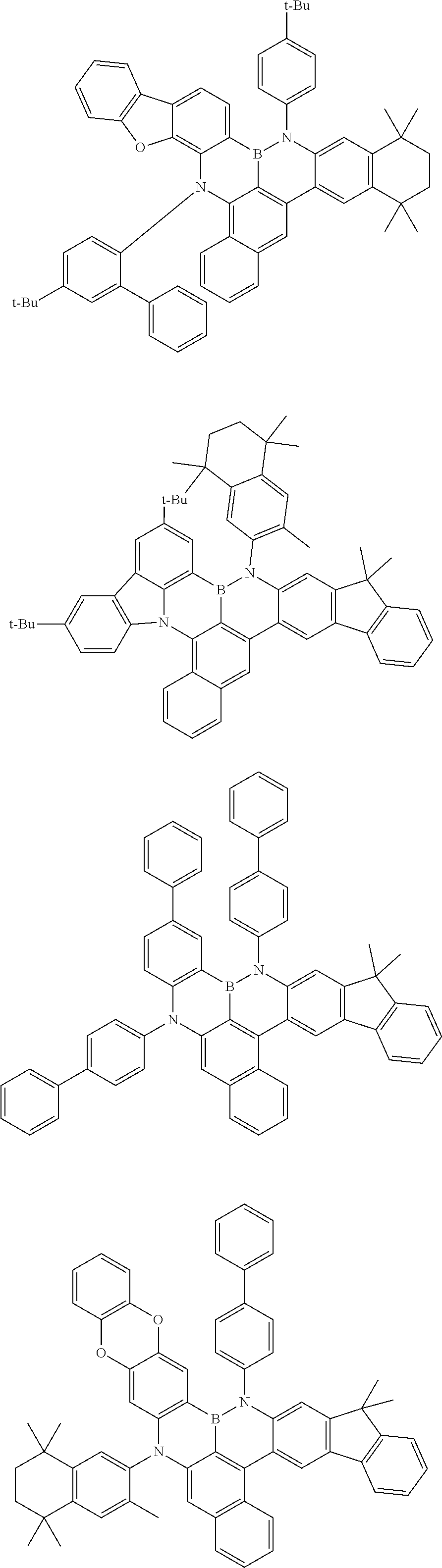 [SMILES: CC(C)(C)c1ccc(N2B3c4ccc5c(oc6ccccc65)c4N(c4ccc(C(C)(C)C)cc4-c4ccccc4)c4c3c(cc3ccccc43)-c3cc4c(cc32)C(C)(C)CCC4(C)C)cc1 ; Cc1cc2c(cc1N1B3c4c(cc5ccccc5c4-n4c5ccc(C(C)(C)C)cc5c5cc(C(C)(C)C)cc3c54)-c3cc4c(cc31)C(C)(C)c1ccccc1-4)C(C)(C)CCC2(C)C ; CC1(C)c2ccccc2-c2cc3c(cc21)N(c1ccc(-c2ccccc2)cc1)B1c2cc(-c4ccccc4)ccc2N(c2ccc(-c4ccccc4)cc2)c2cc4ccccc4c-3c21 ; Cc1cc2c(cc1N1c3cc4c(cc3B3c5c1cc1ccccc1c5-c1cc5c(cc1N3c1ccc(-c3ccccc3)cc1)C(C)(C)c1ccccc1-5)Oc1ccccc1O4)C(C)(C)CCC2(C)C] 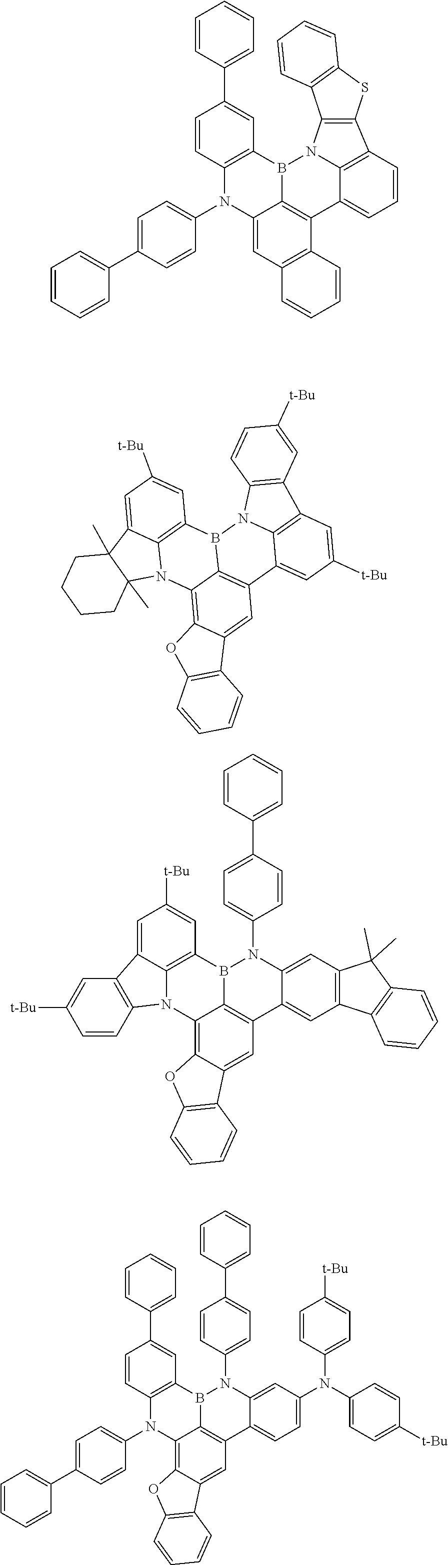 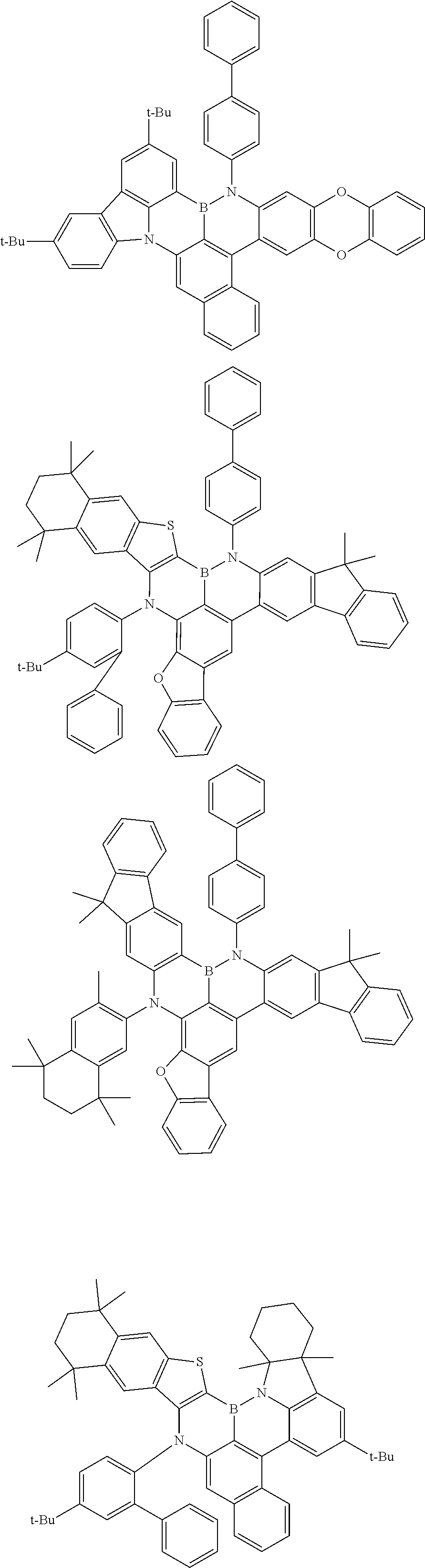 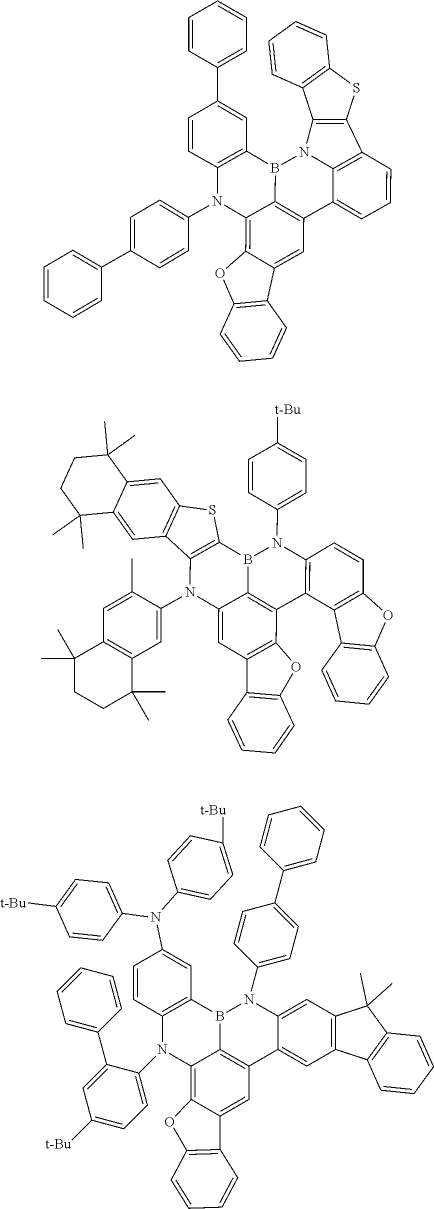 [SMILES: c1ccc(-c2ccc(N3c4ccc(-c5ccccc5)cc4B4c5c(cc6c(oc7ccccc76)c53)-c3cccc5c6sc7ccccc7c6n4c35)cc2)cc1 ; Cc1cc2c(cc1N1c3cc4c(oc5ccccc54)c4c3B(c3sc5cc6c(cc5c31)C(C)(C)CCC6(C)C)N(c1ccc(C(C)(C)C)cc1)c1ccc3oc5ccccc5c3c1-4)C(C)(C)CCC2(C)C ; CC(C)(C)c1ccc(N(c2ccc(C(C)(C)C)cc2)c2ccc3c(c2)B2c4c(cc5c(oc6ccccc65)c4N3c3ccc(C(C)(C)C)cc3-c3ccccc3)-c3cc4c(cc3N2c2ccc(-c3ccccc3)cc2)C(C)(C)c2ccccc2-4)cc1] 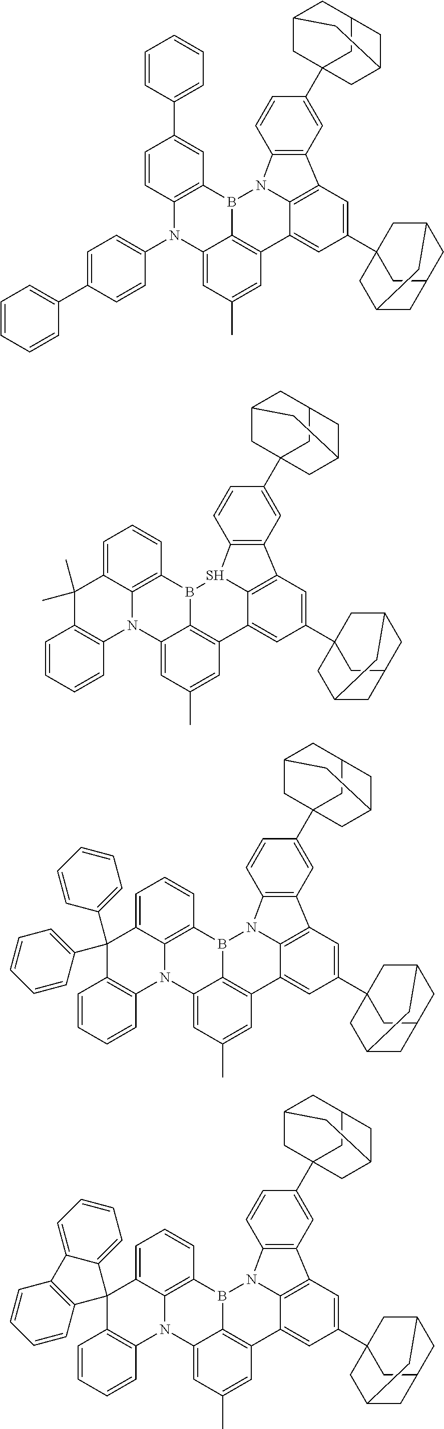 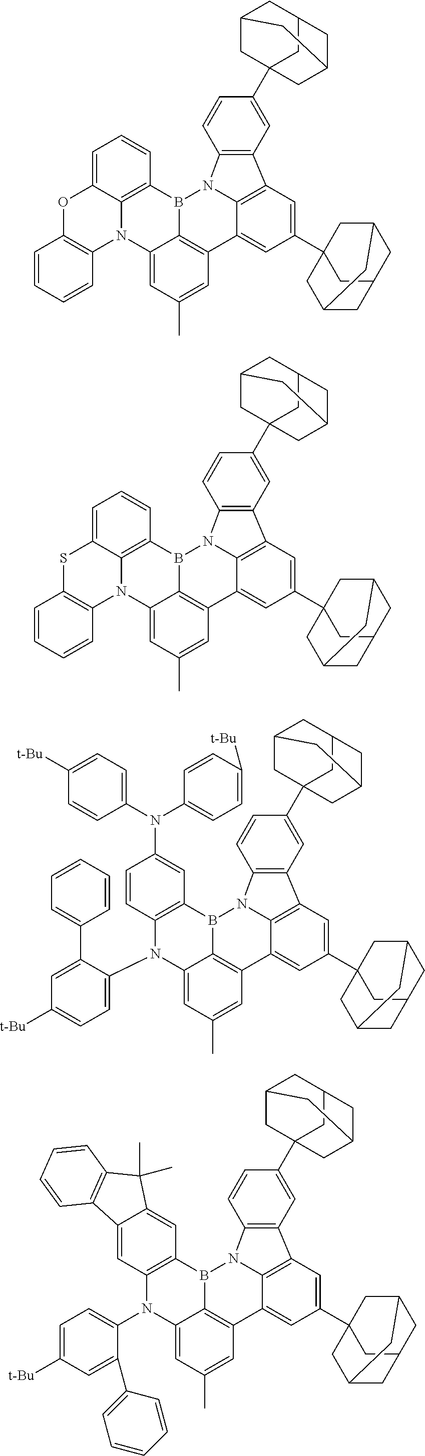 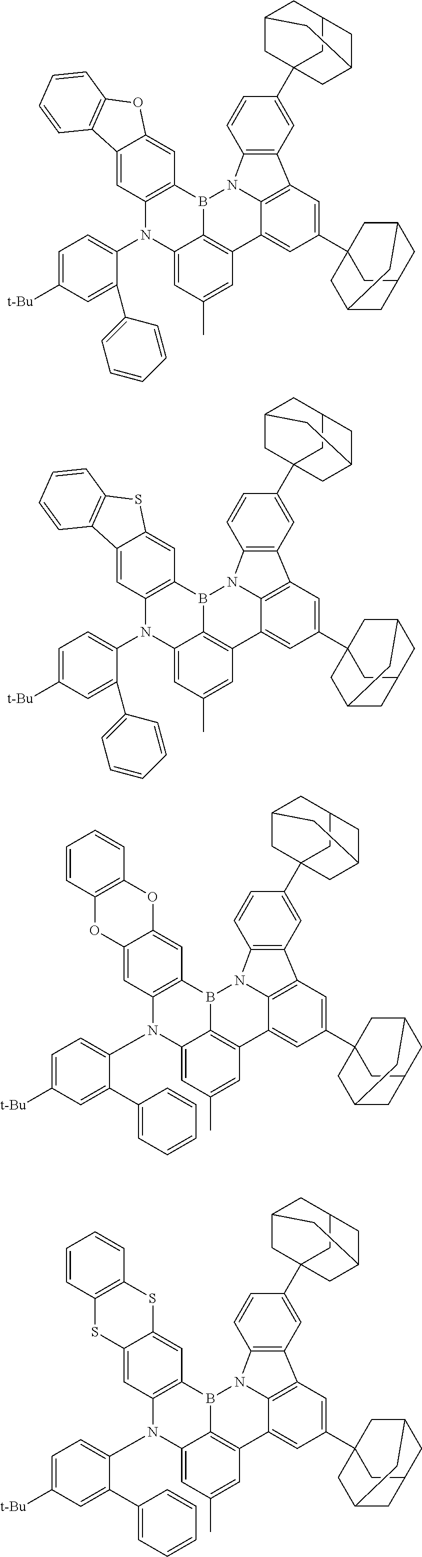 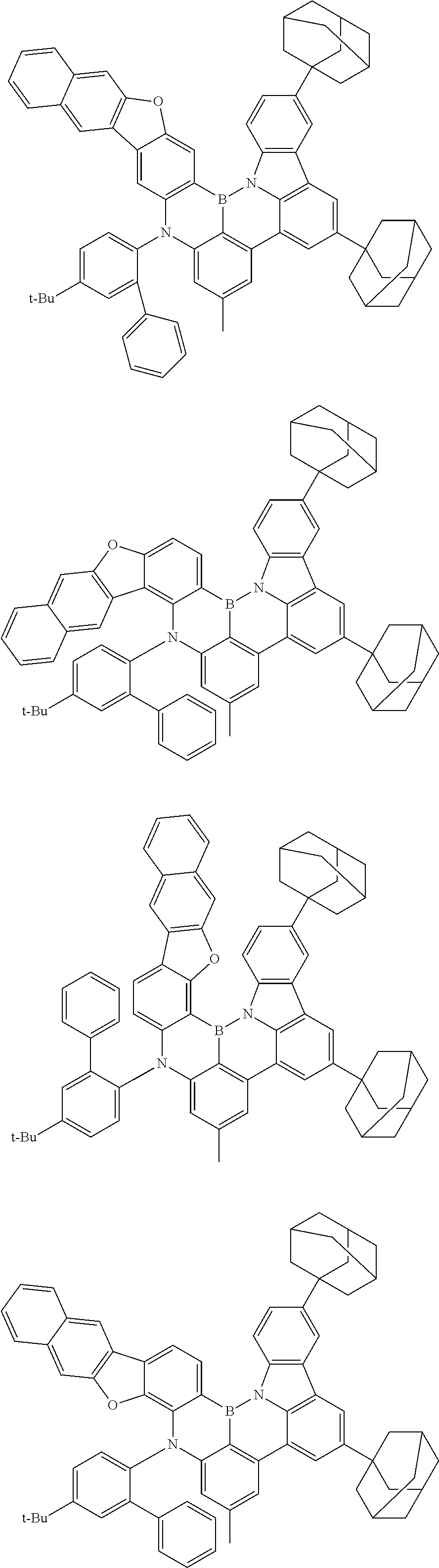 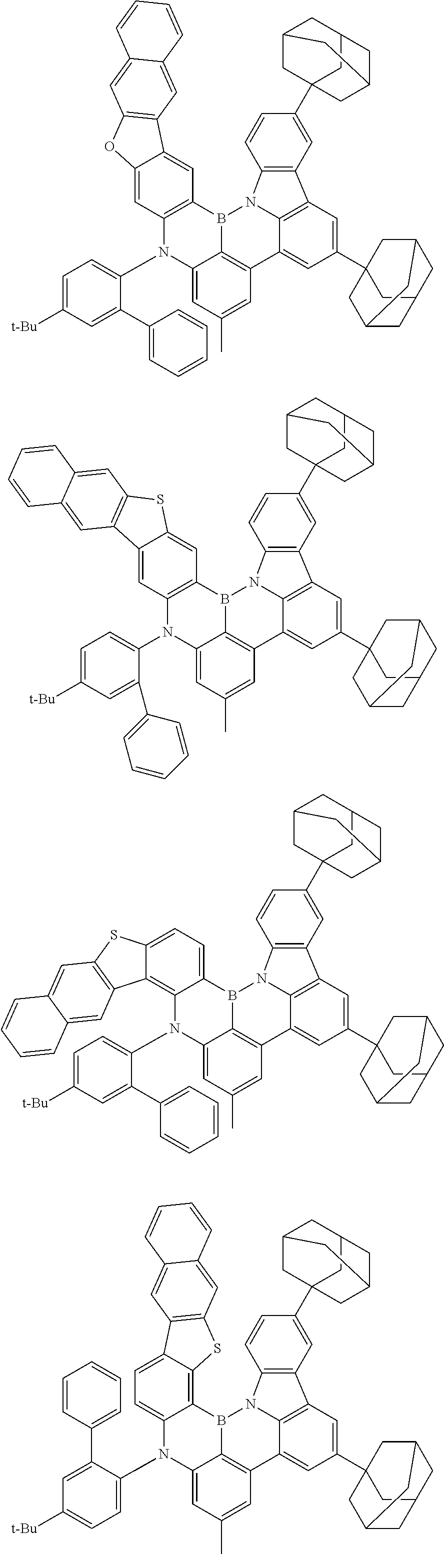 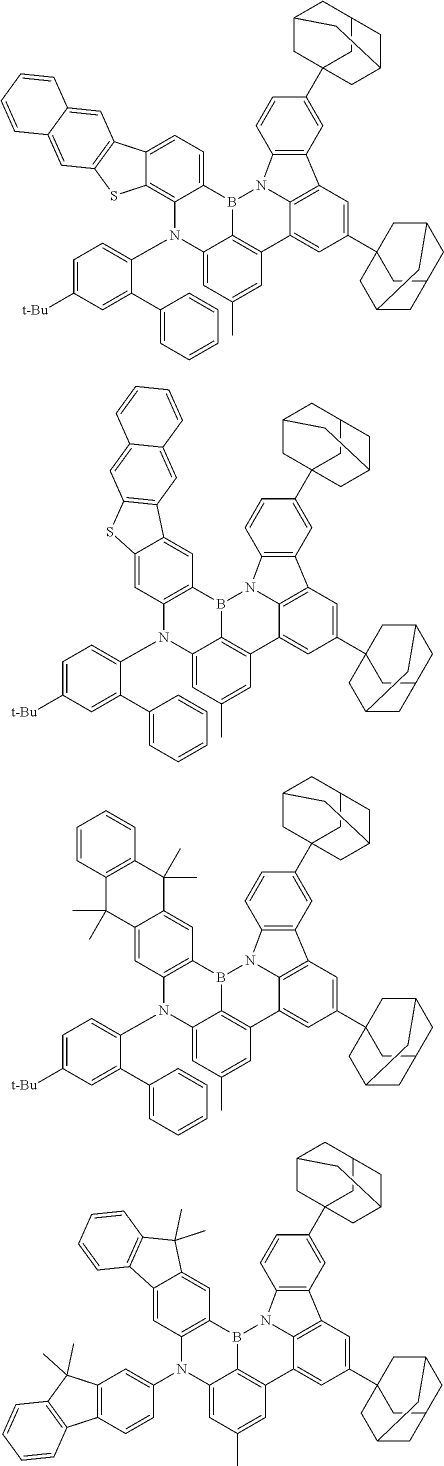 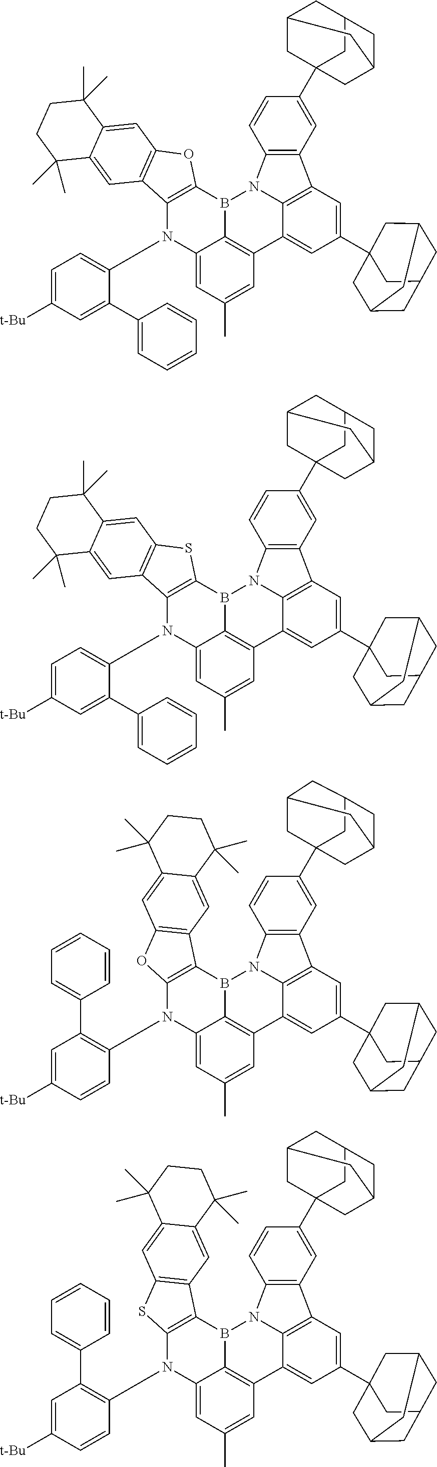 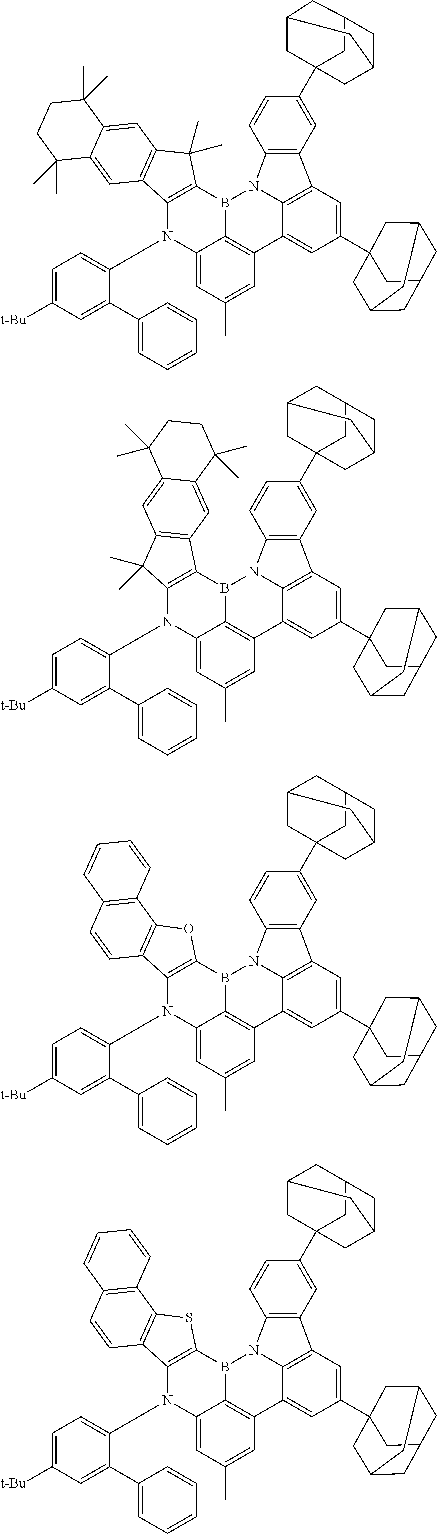 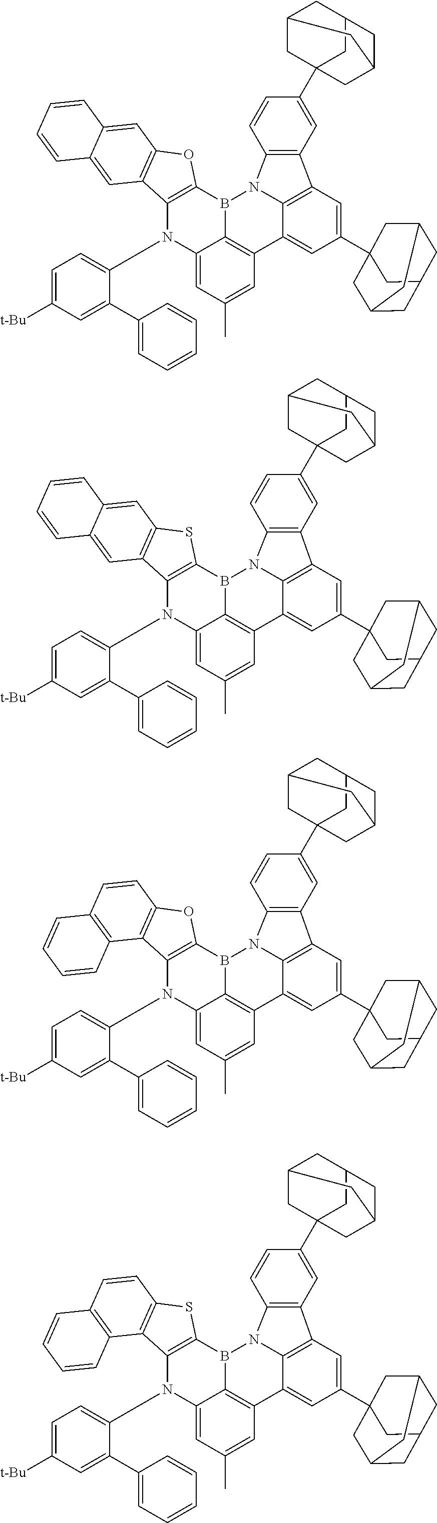 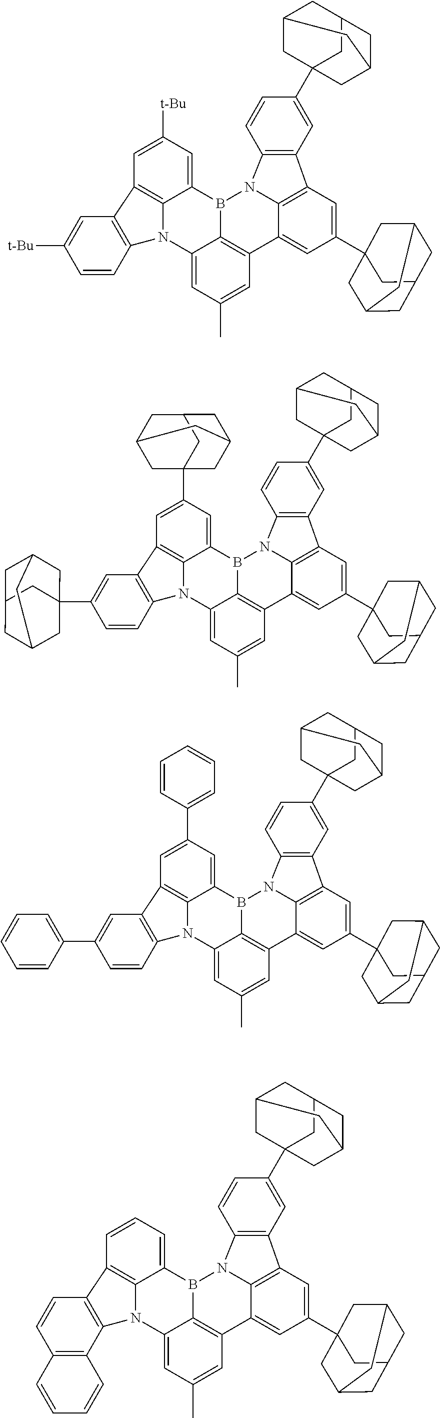 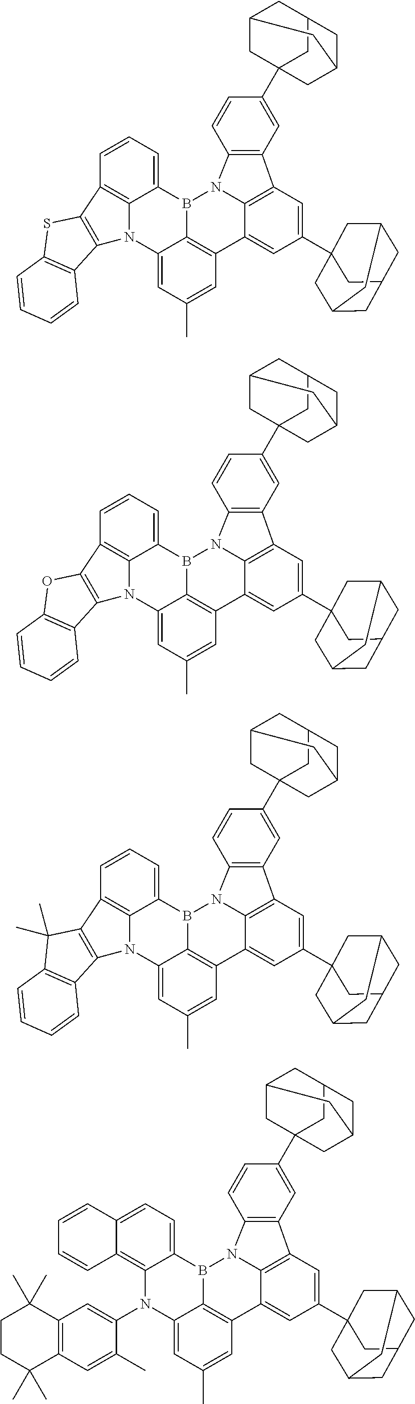 [SMILES: Cc1cc2c3c(c1)-n1c4c(cccc4c4sc5ccccc5c41)B3n1c3ccc(C45CC6CC(CC(C6)C4)C5)cc3c3cc(C45CC6CC(CC(C6)C4)C5)cc-2c31 ; Cc1cc2c3c(c1)-n1c4c(cccc4c4oc5ccccc5c41)B3n1c3ccc(C45CC6CC(CC(C6)C4)C5)cc3c3cc(C45CC6CC(CC(C6)C4)C5)cc-2c31 ; Cc1cc2c3c(c1)-n1c4c(c5cccc(c51)B3n1c3ccc(C56CC7CC(CC(C7)C5)C6)cc3c3cc(C56CC7CC(CC(C7)C5)C6)cc-2c31)C(C)(C)c1ccccc1-4 ; Cc1cc2c3c(c1)N(c1cc4c(cc1C)C(C)(C)CCC4(C)C)c1c(ccc4ccccc14)B3n1c3ccc(C45CC6CC(CC(C6)C4)C5)cc3c3cc(C45CC6CC(CC(C6)C4)C5)cc-2c31] 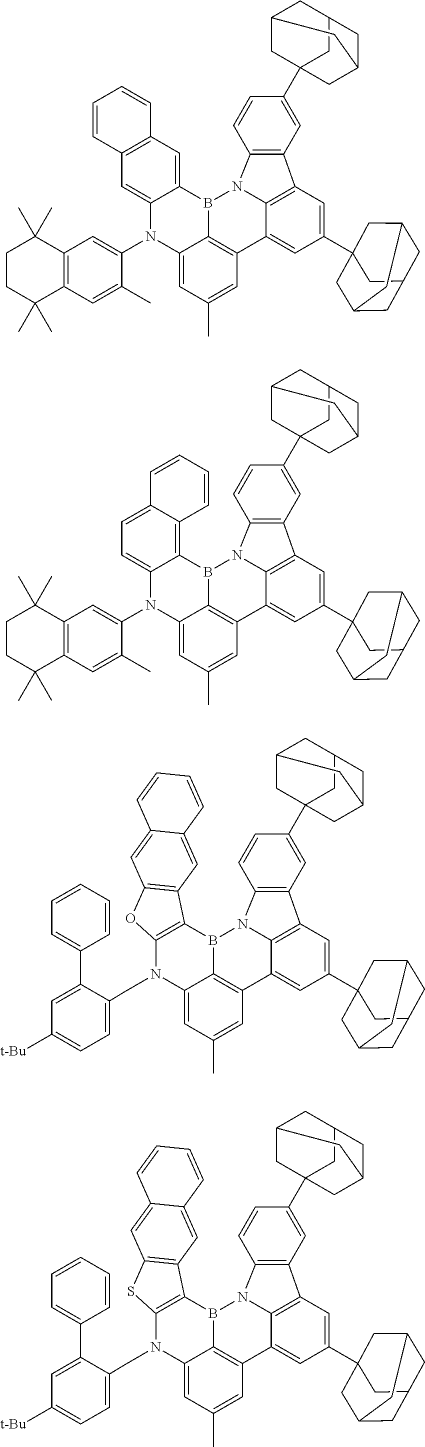 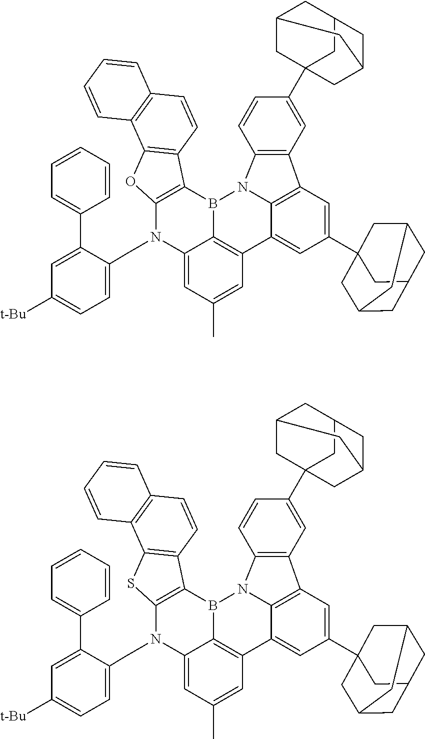 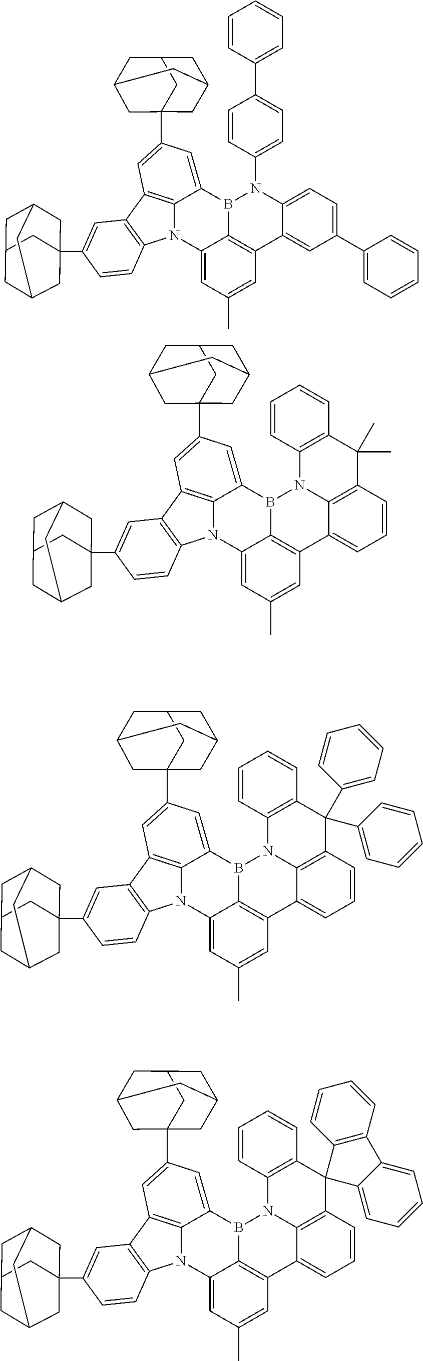 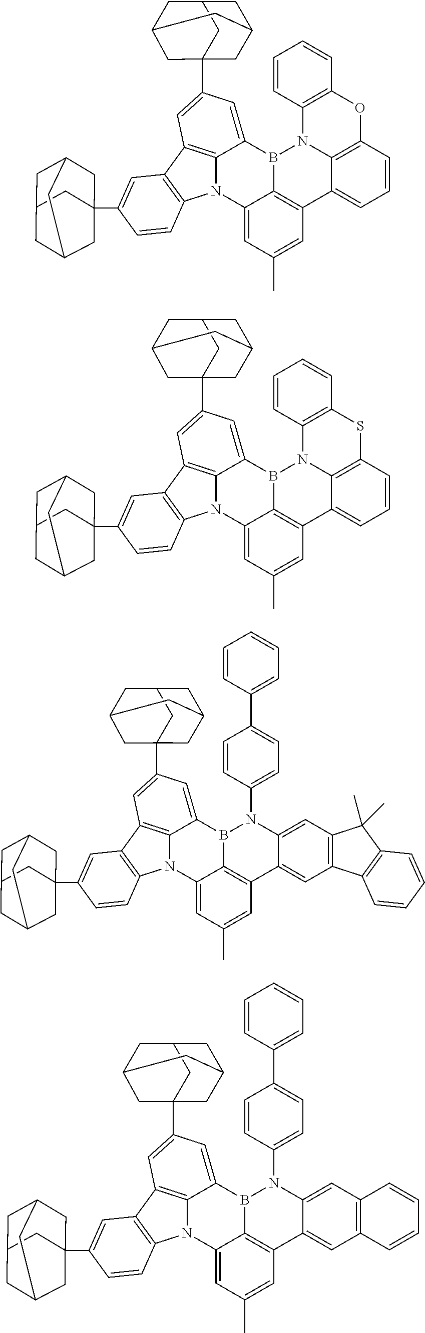 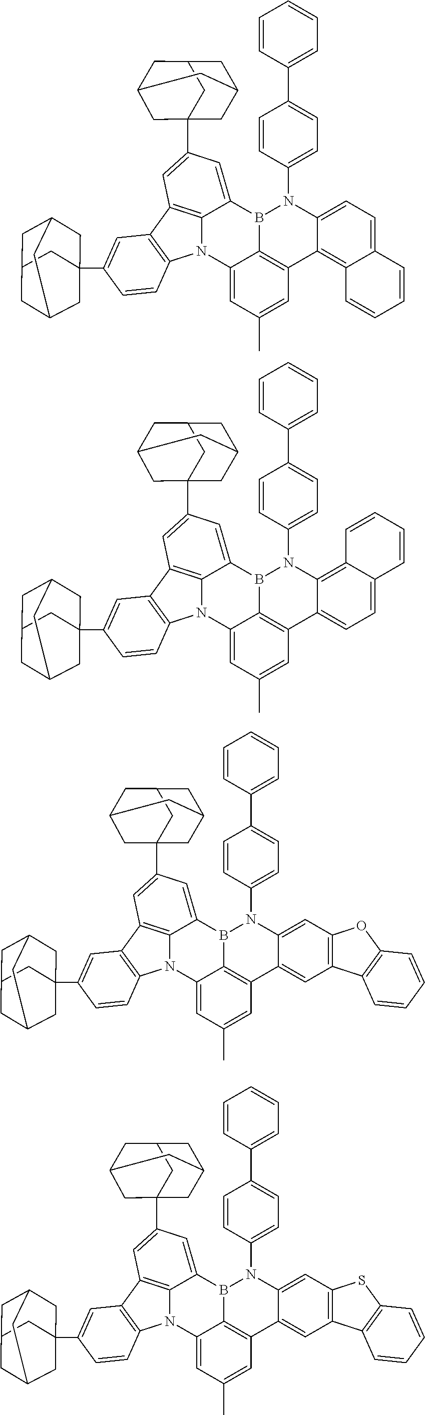 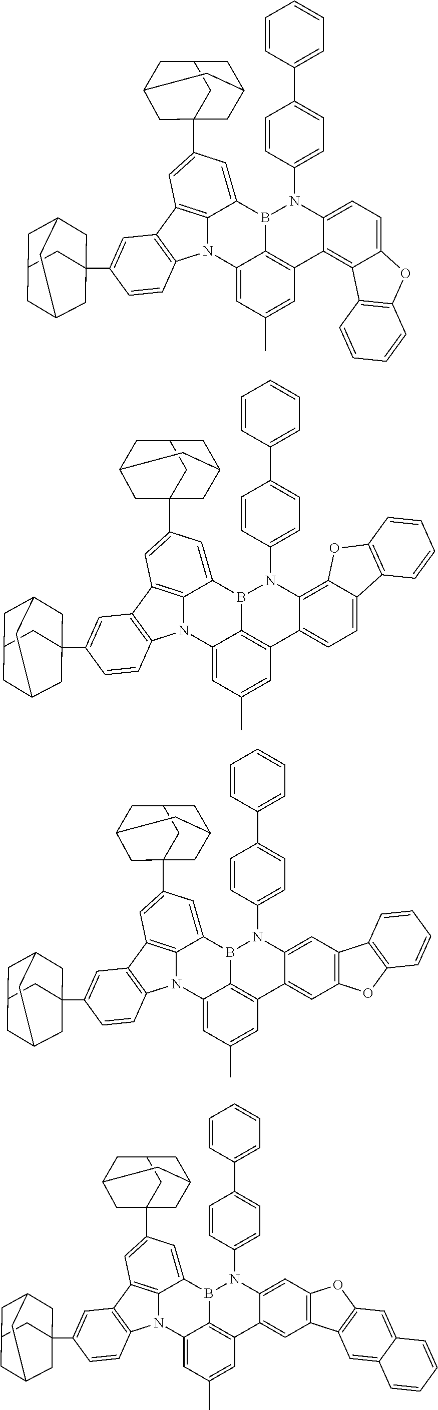 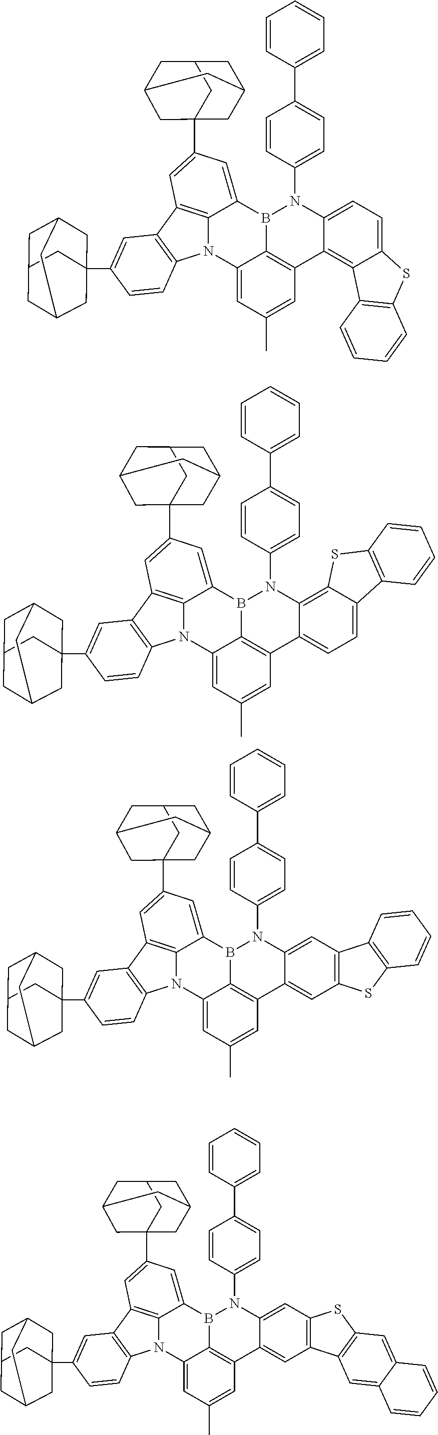 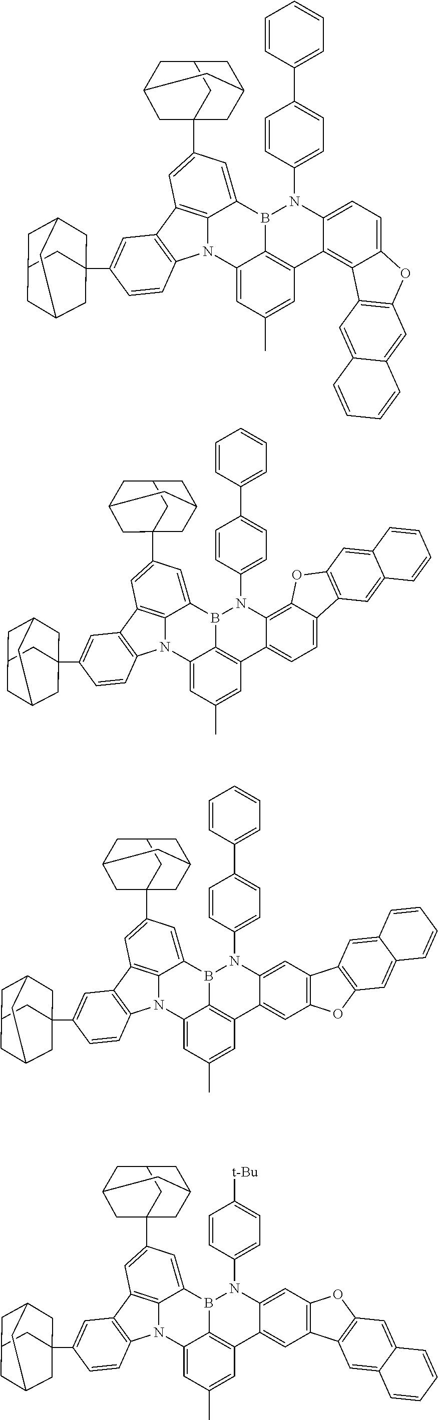 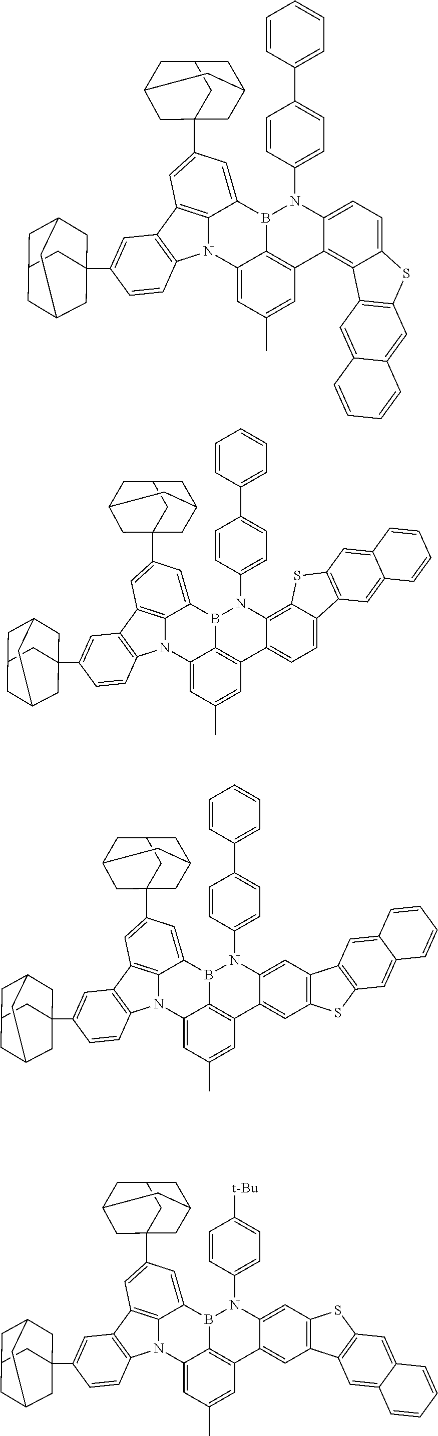 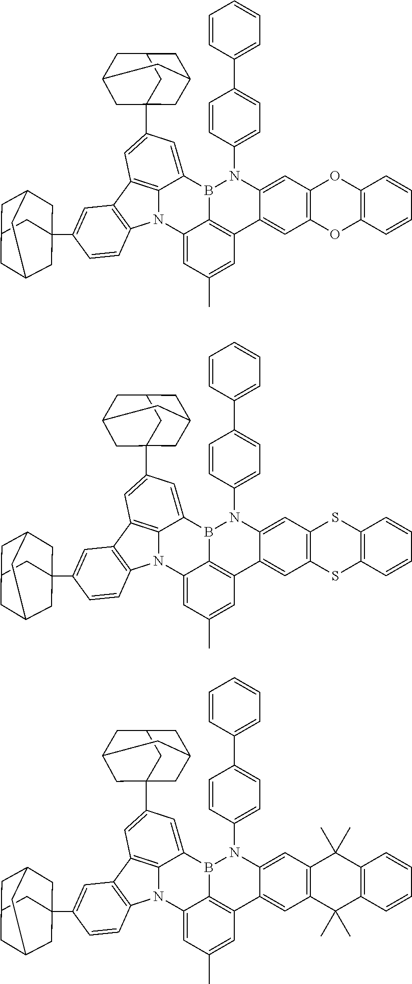 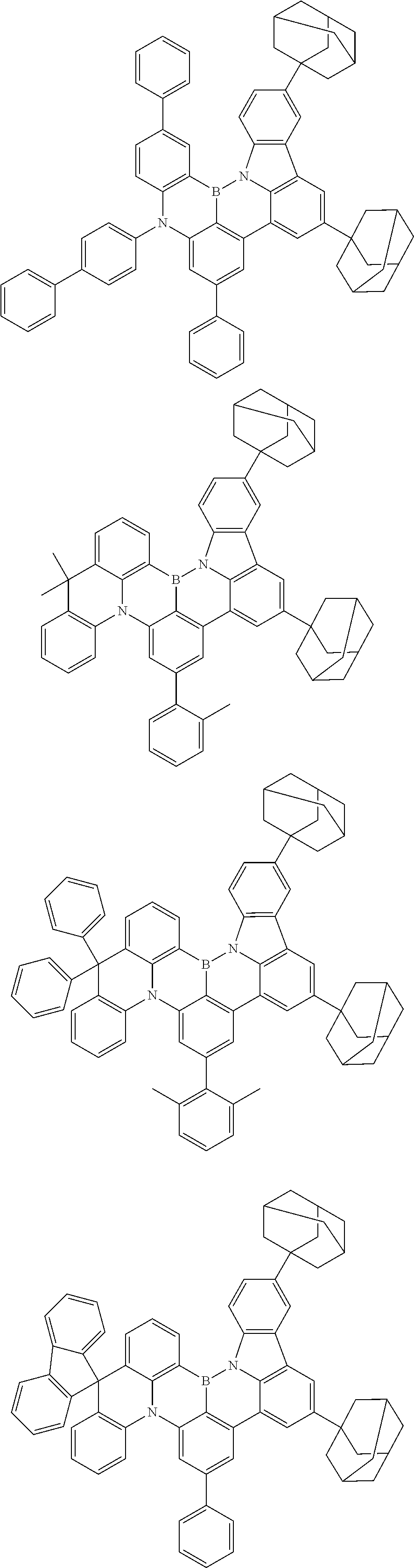 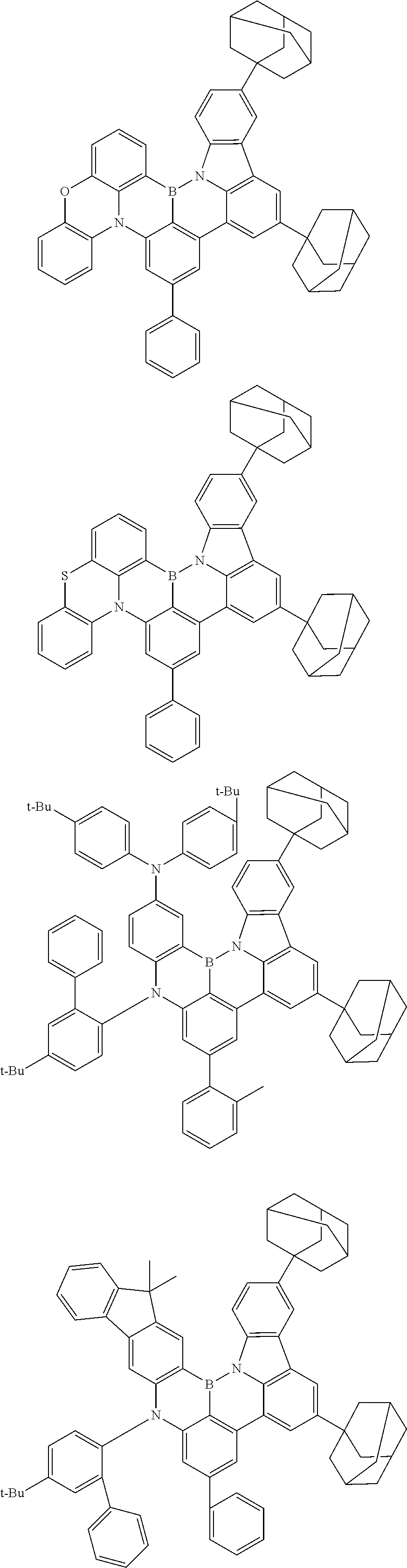 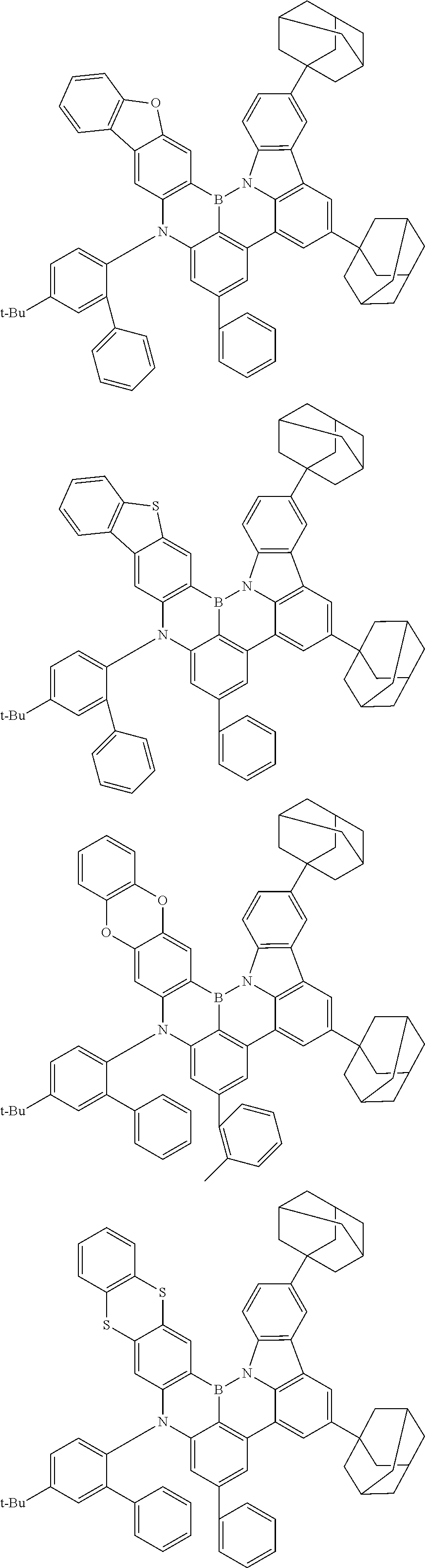 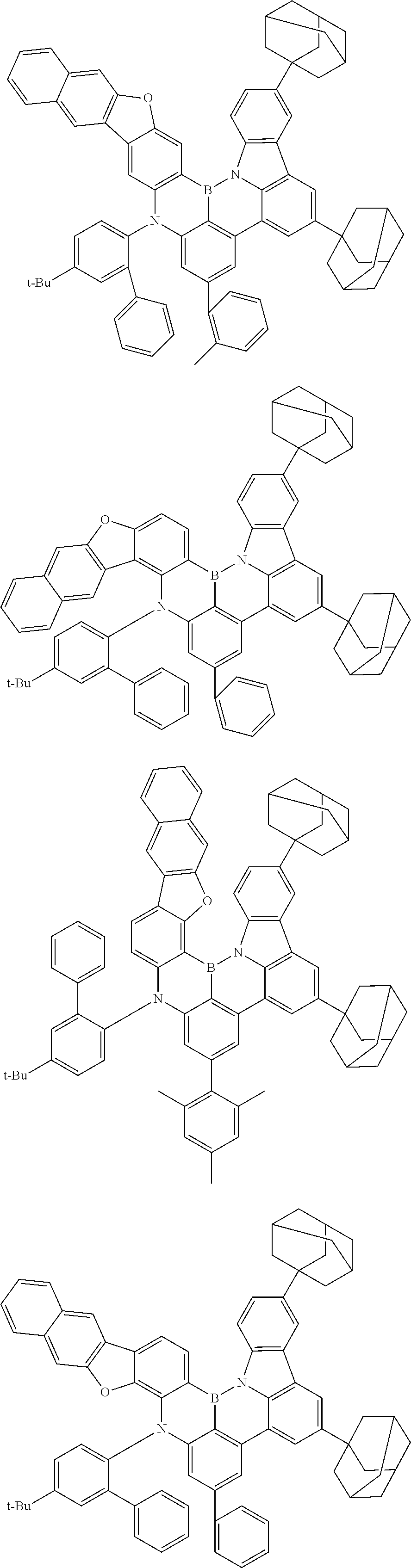 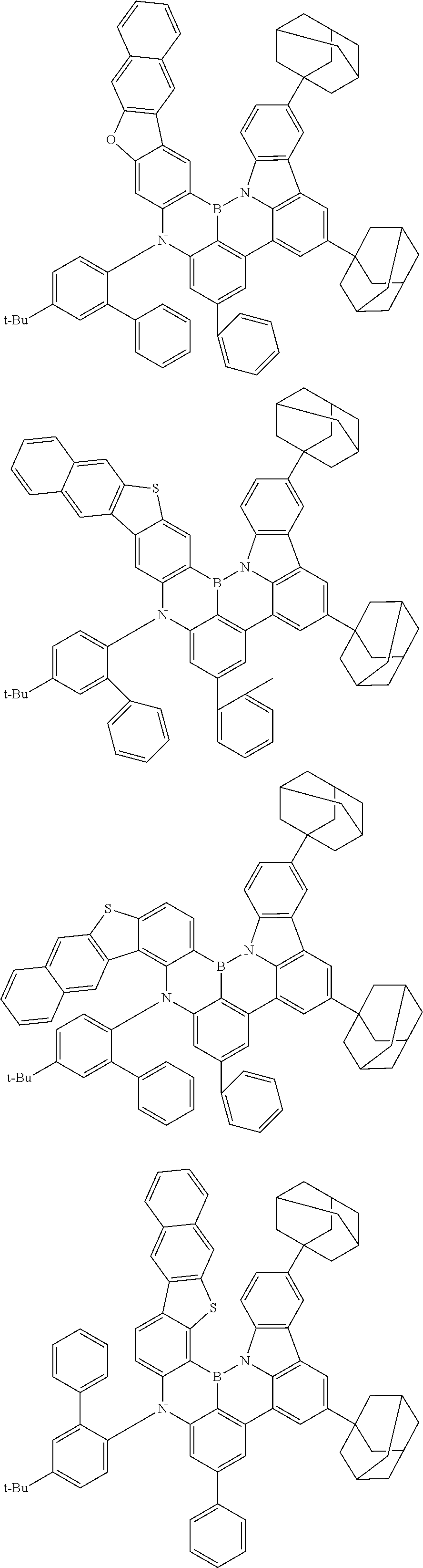 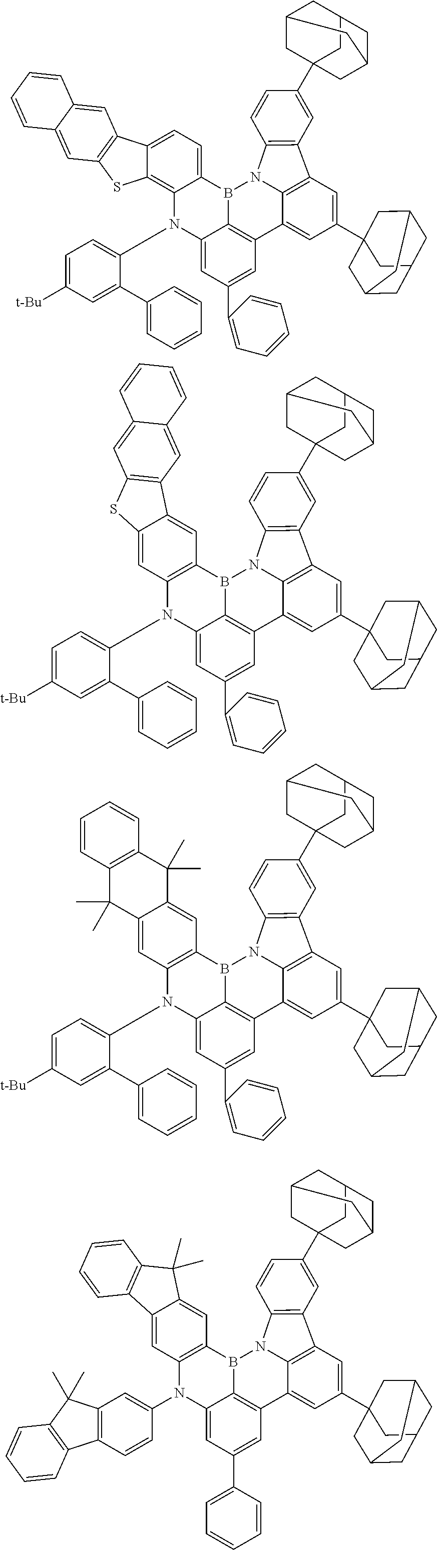 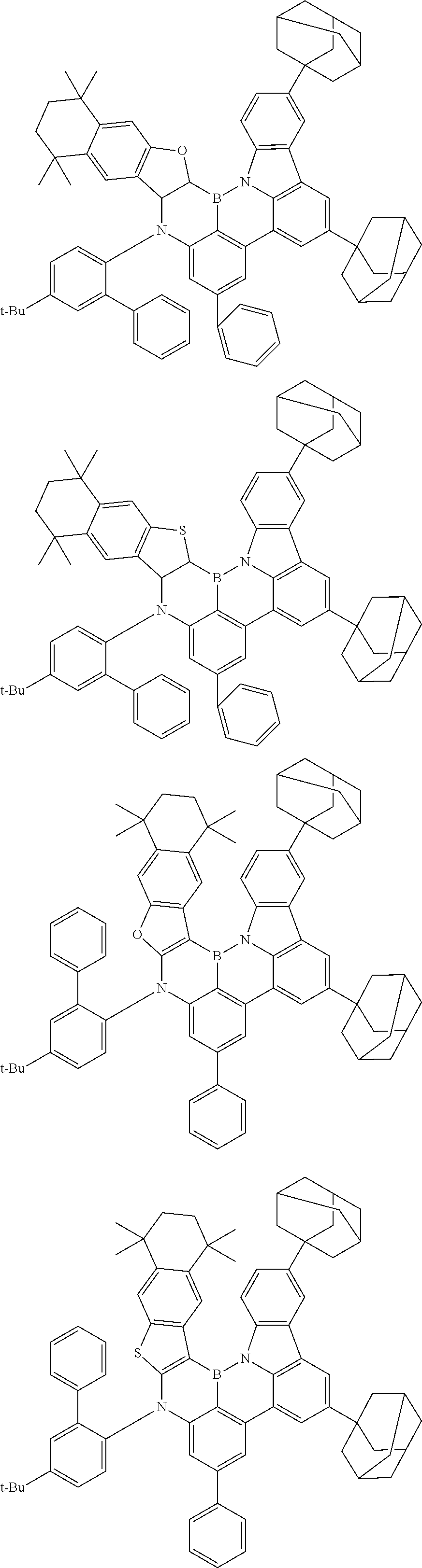 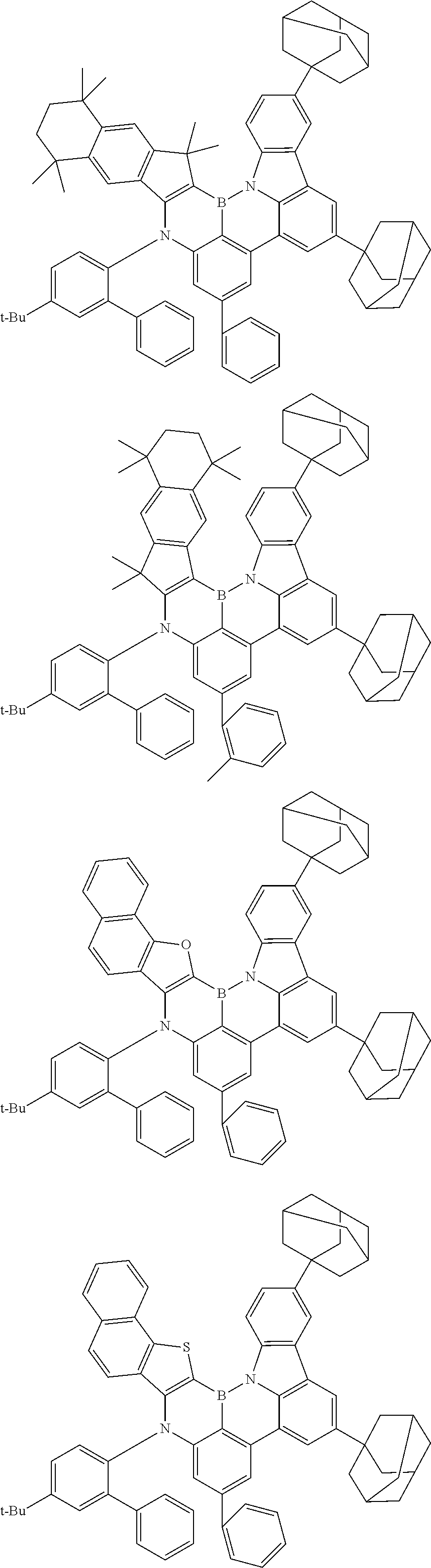 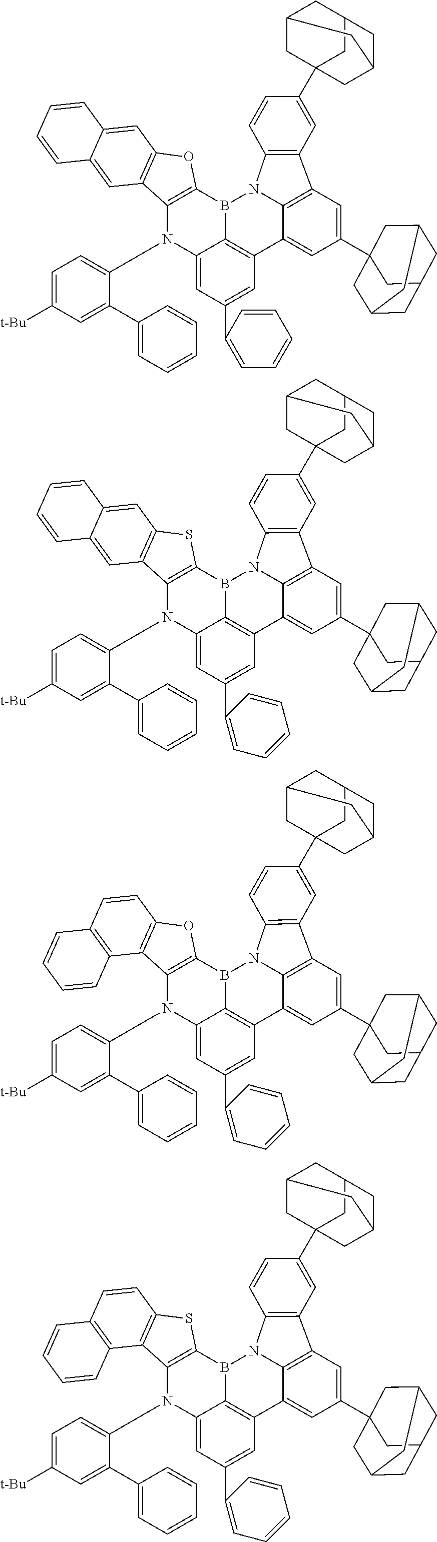 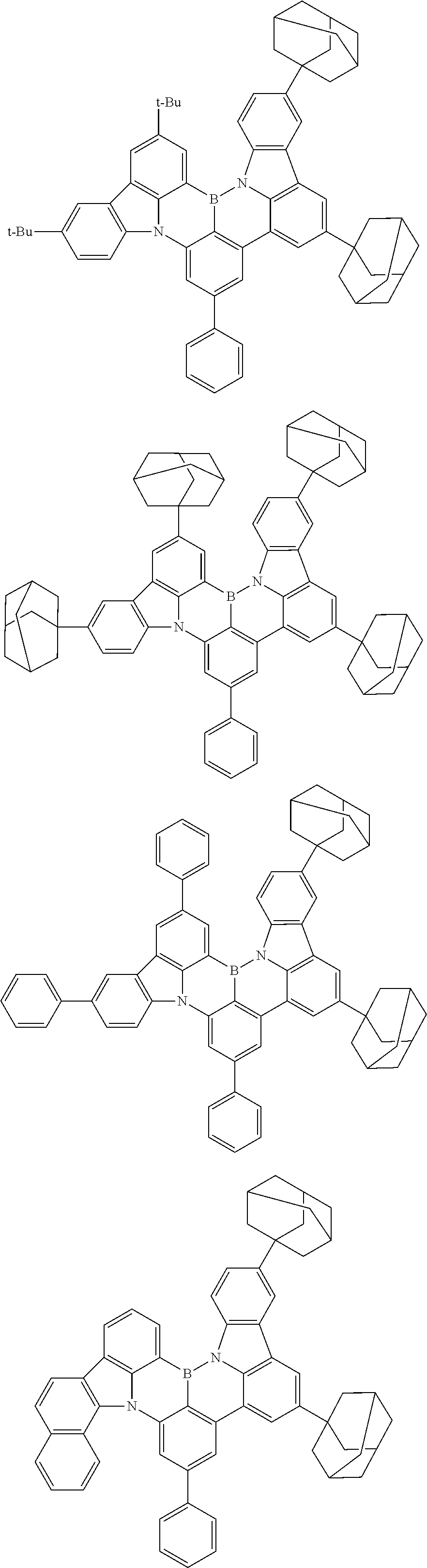 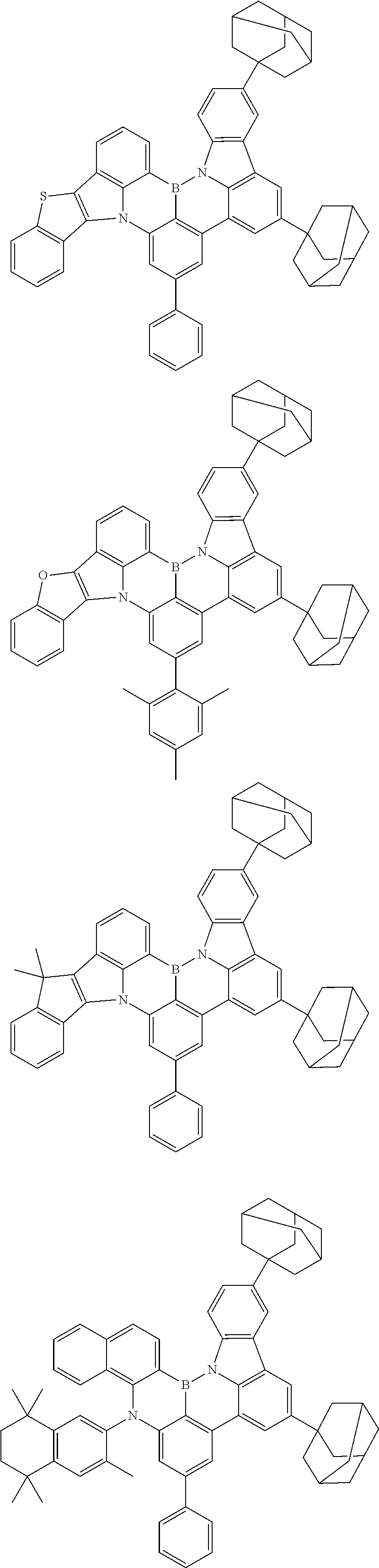 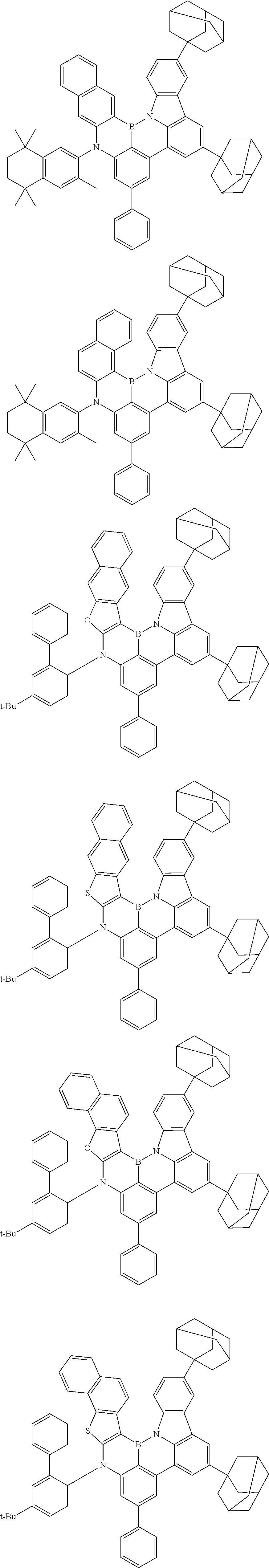 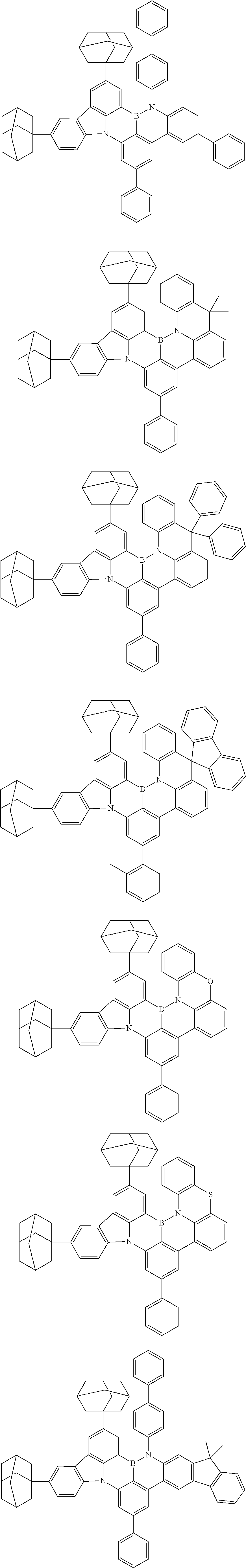 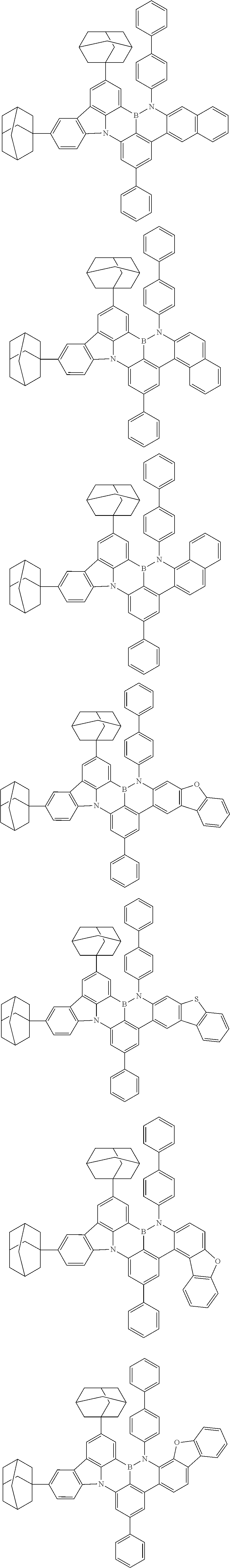 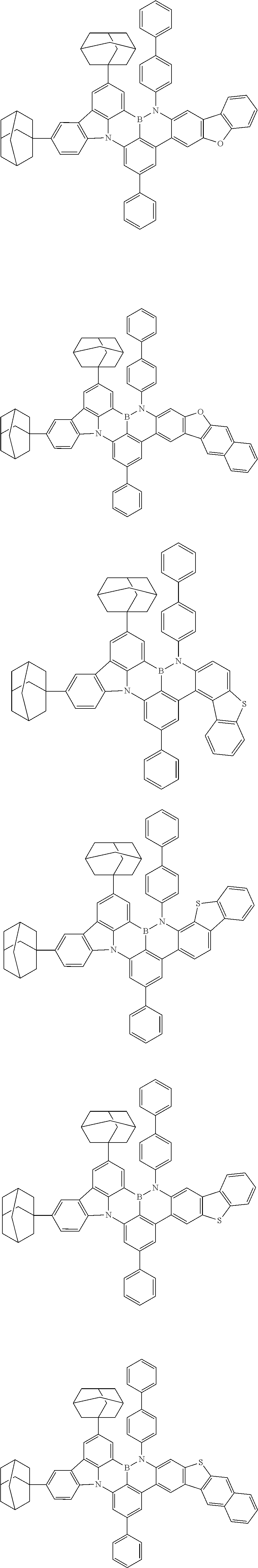 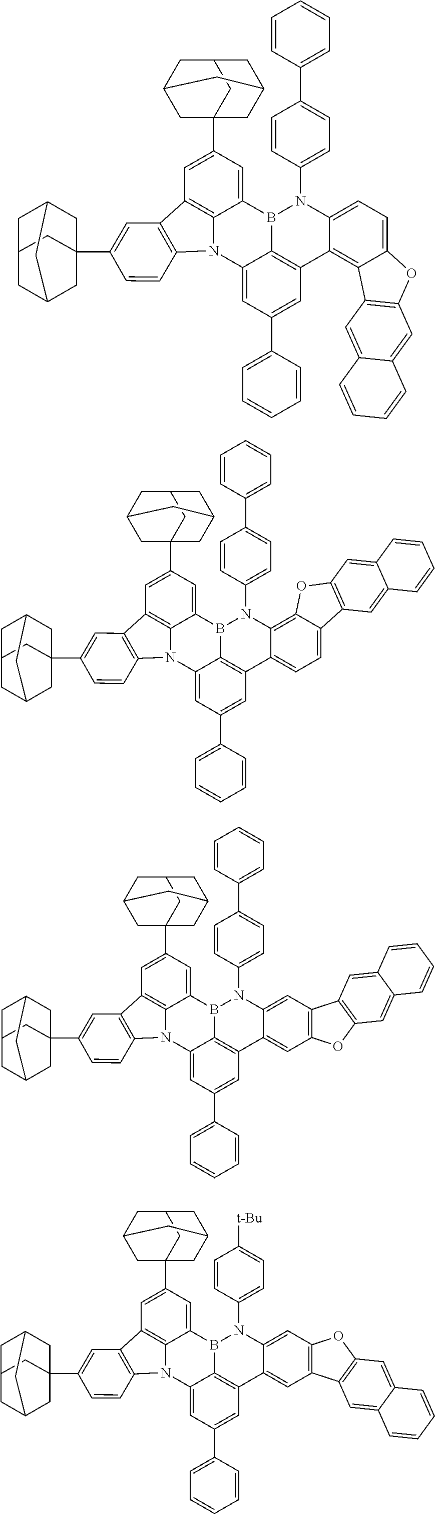 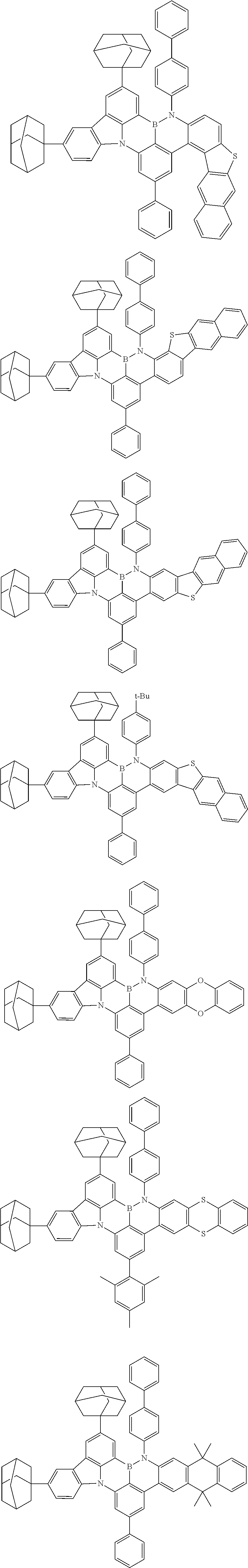 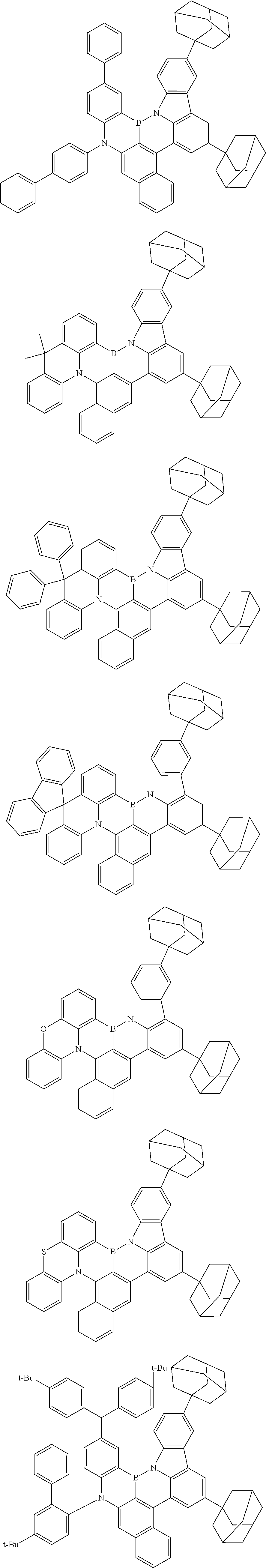 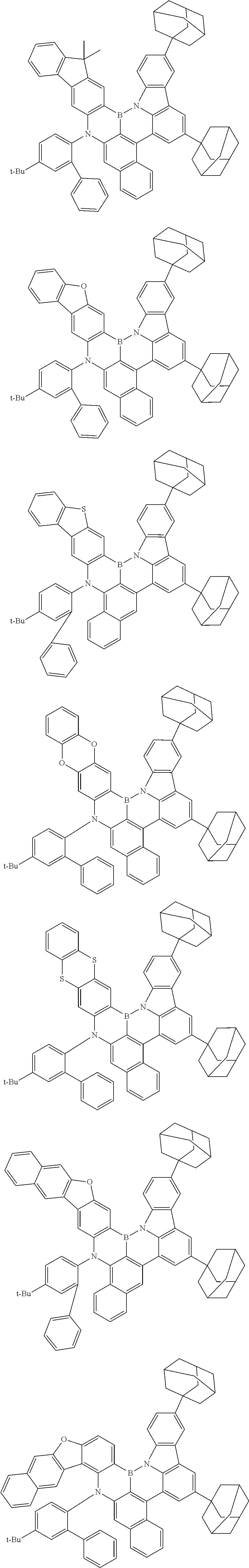 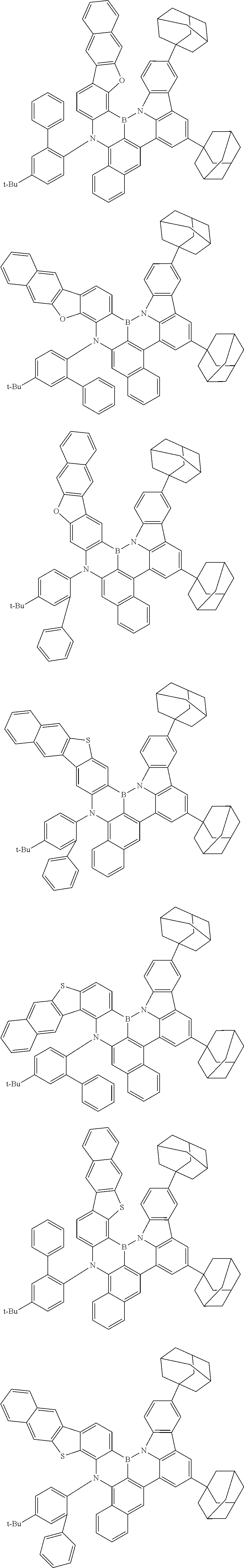 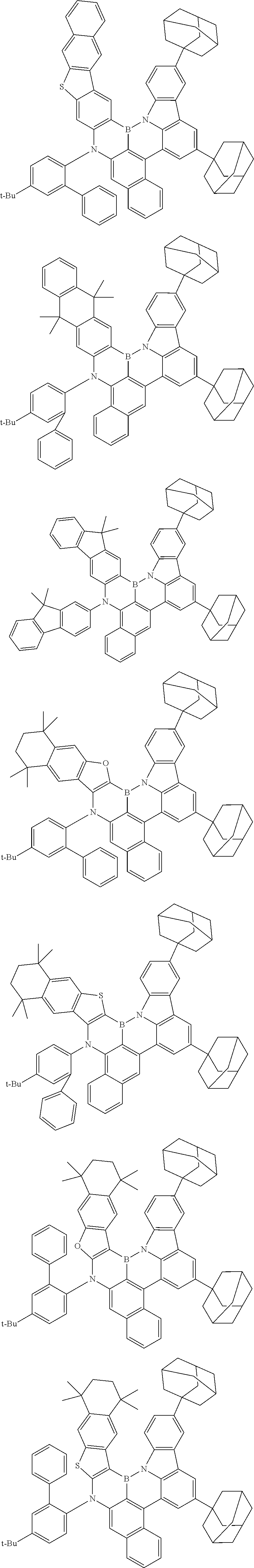 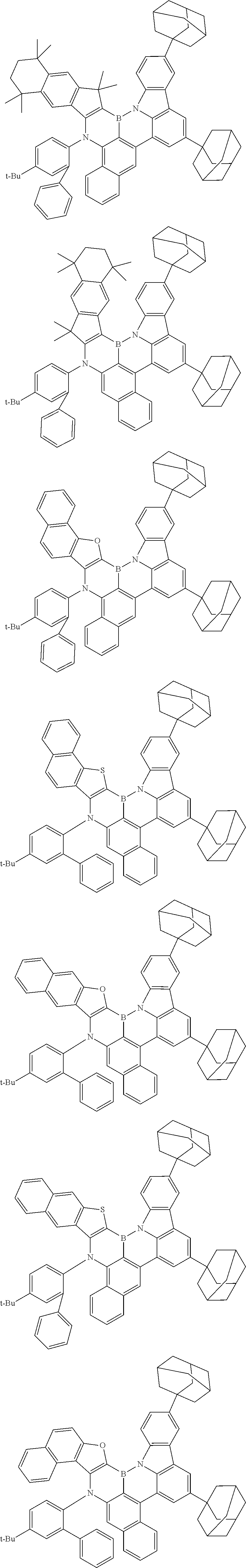 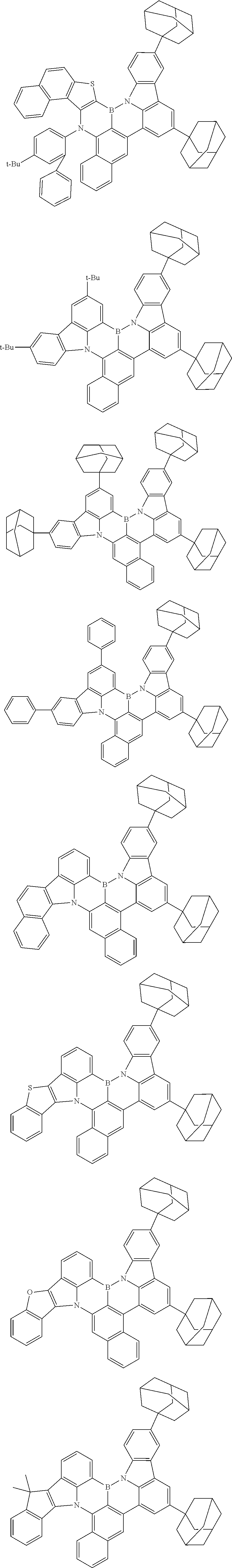 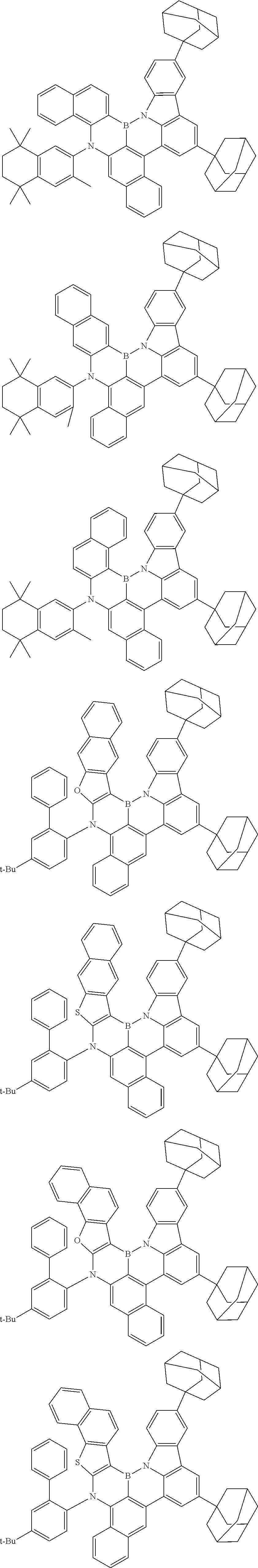 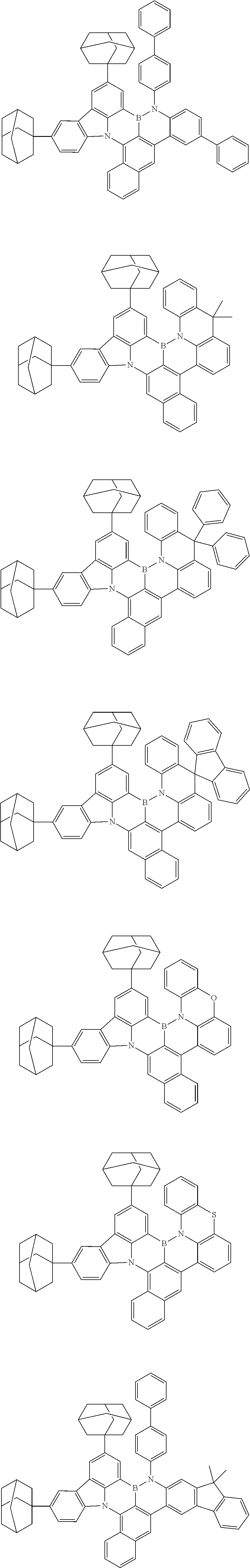 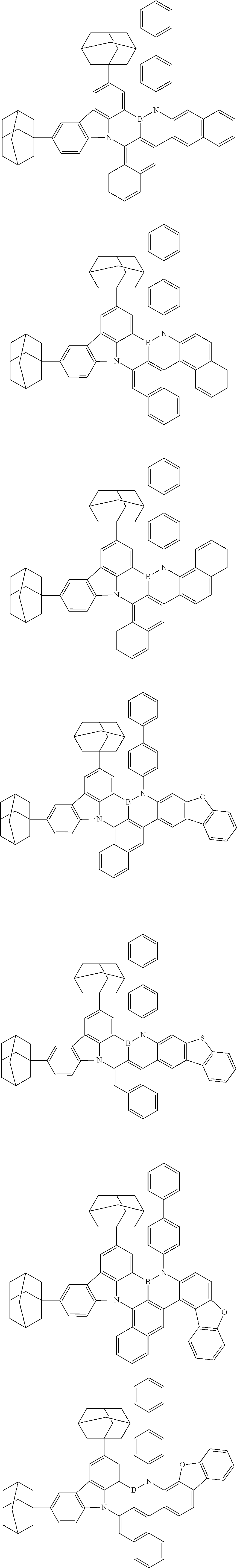 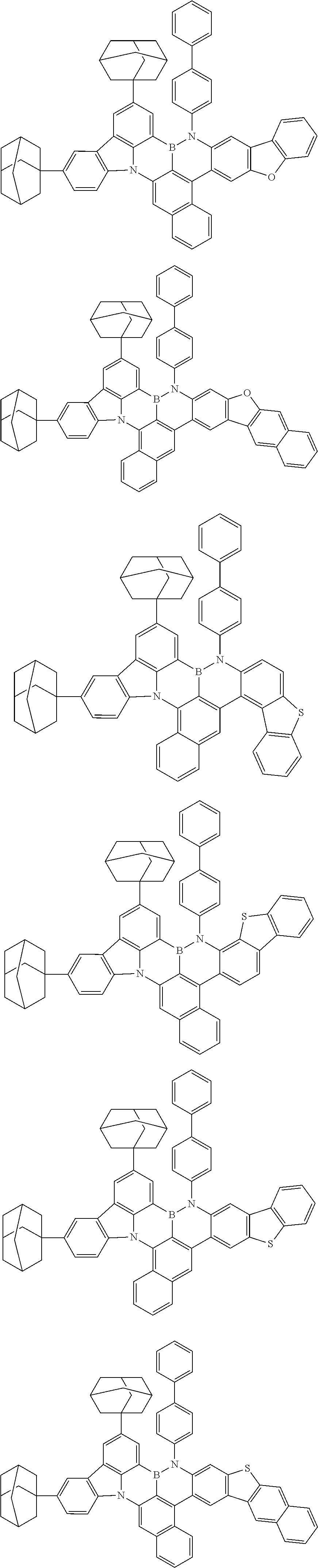 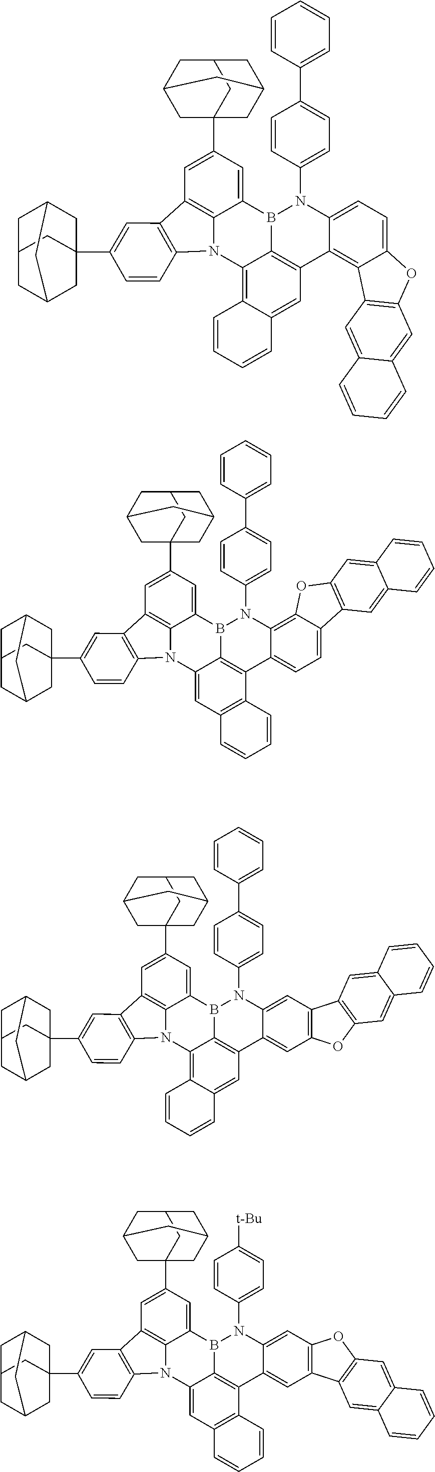 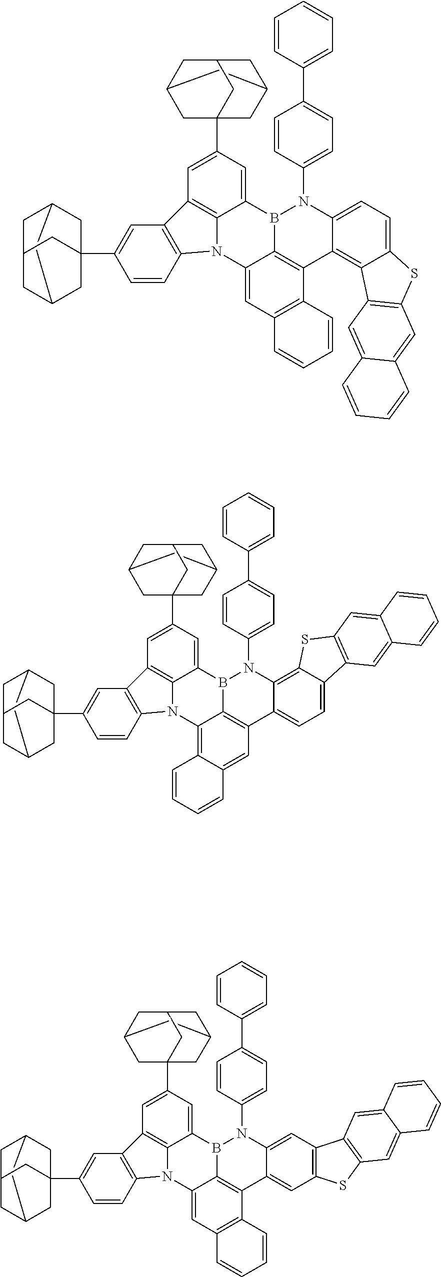 [SMILES: c1ccc(-c2ccc(N3B4c5c(cc6ccccc6c5-c5c3ccc3sc6cc7ccccc7cc6c53)-n3c5ccc(C67CC8CC(CC(C8)C6)C7)cc5c5cc(C67CC8CC(CC(C8)C6)C7)cc4c53)cc2)cc1 ; c1ccc(-c2ccc(N3B4c5c(cc6ccccc6c5-n5c6ccc(C78CC9CC(CC(C9)C7)C8)cc6c6cc(C78CC9CC(CC(C9)C7)C8)cc4c65)-c4ccc5c(sc6cc7ccccc7cc65)c43)cc2)cc1 ; c1ccc(-c2ccc(N3B4c5c(cc6ccccc6c5-c5cc6sc7cc8ccccc8cc7c6cc53)-n3c5ccc(C67CC8CC(CC(C8)C6)C7)cc5c5cc(C67CC8CC(CC(C8)C6)C7)cc4c53)cc2)cc1] 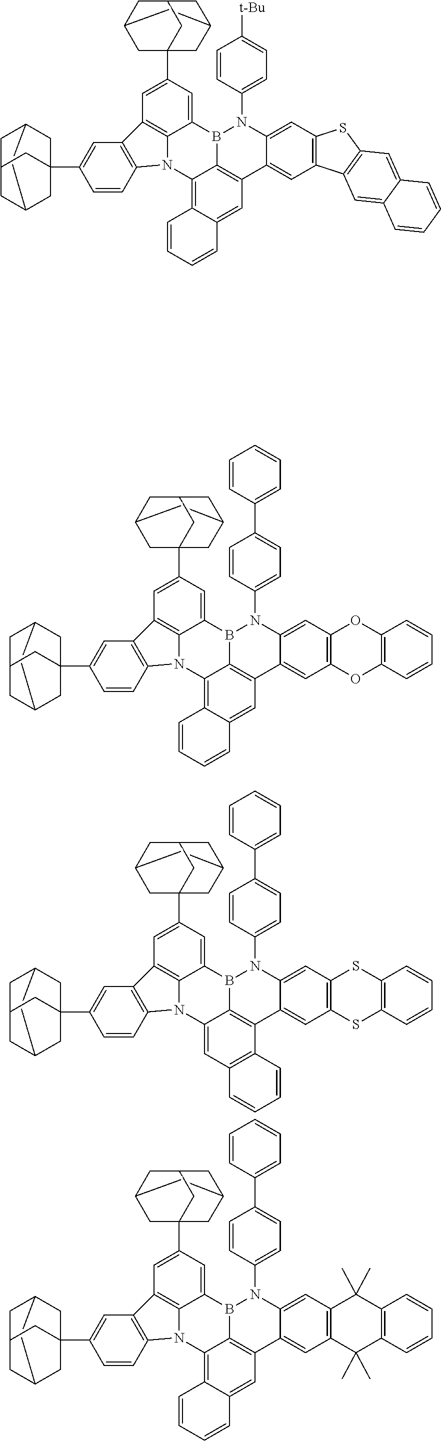 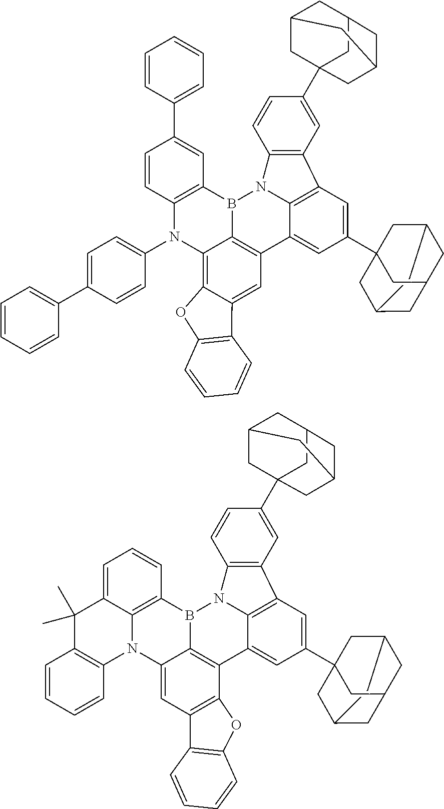 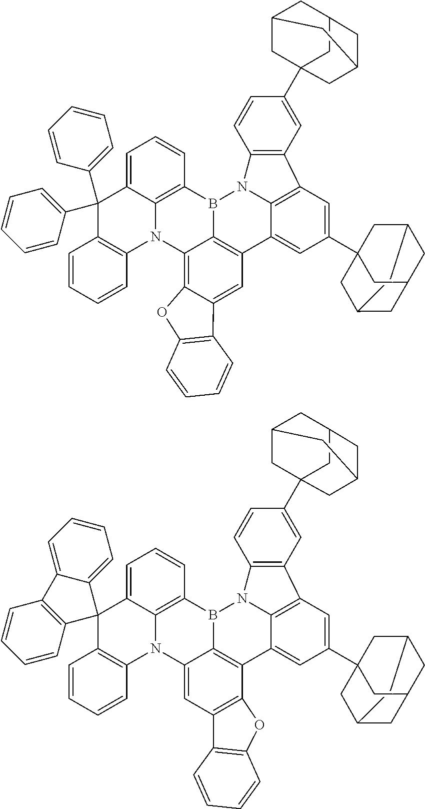 [SMILES: c1ccc(C2(c3ccccc3)c3ccccc3N3c4c(cccc42)B2c4c(cc5c(oc6ccccc65)c43)-c3cc(C45CC6CC(CC(C6)C4)C5)cc4c5cc(C67CC8CC(CC(C8)C6)C7)ccc5n2c34)cc1 ; c1ccc2c(c1)-c1ccccc1C21c2ccccc2N2c3cc4c(oc5ccccc54)c4c3B(c3cccc1c32)n1c2ccc(C35CC6CC(CC(C6)C3)C5)cc2c2cc(C35CC6CC(CC(C6)C3)C5)cc-4c21] 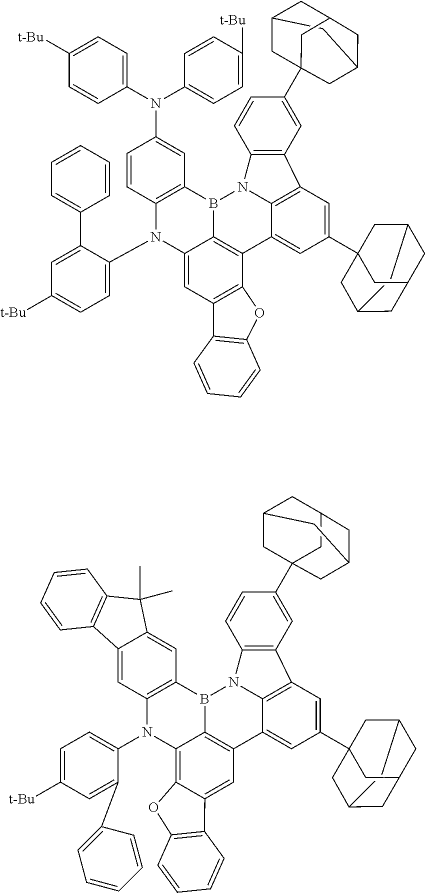 [SMILES: CC(C)(C)c1ccc(N(c2ccc(C(C)(C)C)cc2)c2ccc3c(c2)B2c4c(cc5c(oc6ccccc65)c4-c4cc(C56CC7CC(CC(C7)C5)C6)cc5c6cc(C78CC9CC(CC(C9)C7)C8)ccc6n2c45)N3c2ccc(C(C)(C)C)cc2-c2ccccc2)cc1 ; CC(C)(C)c1ccc(N2c3cc4c(cc3B3c5c(cc6c(oc7ccccc76)c52)-c2cc(C56CC7CC(CC(C7)C5)C6)cc5c6cc(C78CC9CC(CC(C9)C7)C8)ccc6n3c25)C(C)(C)c2ccccc2-4)c(-c2ccccc2)c1] 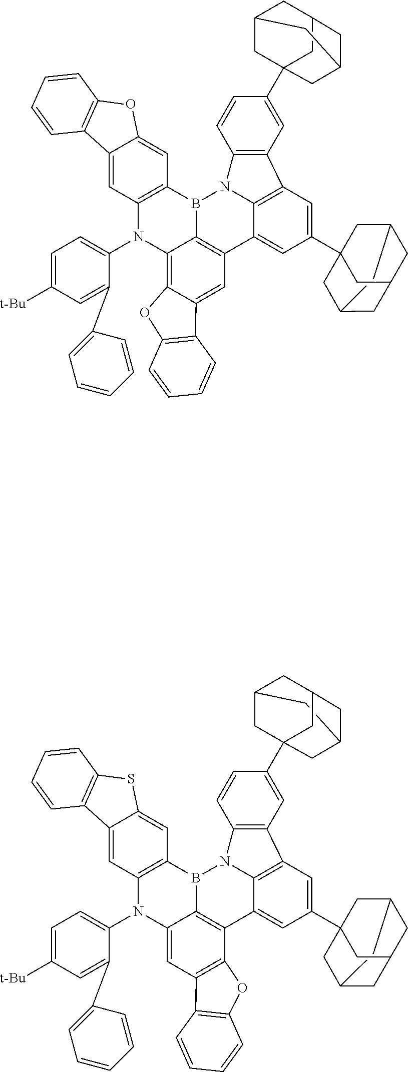 [SMILES: CC(C)(C)c1ccc(N2c3cc4c(cc3B3c5c(cc6c(oc7ccccc76)c52)-c2cc(C56CC7CC(CC(C7)C5)C6)cc5c6cc(C78CC9CC(CC(C9)C7)C8)ccc6n3c25)oc2ccccc24)c(-c2ccccc2)c1 ; CC(C)(C)c1ccc(N2c3cc4c(cc3B3c5c2cc2c(oc6ccccc62)c5-c2cc(C56CC7CC(CC(C7)C5)C6)cc5c6cc(C78CC9CC(CC(C9)C7)C8)ccc6n3c25)sc2ccccc24)c(-c2ccccc2)c1] 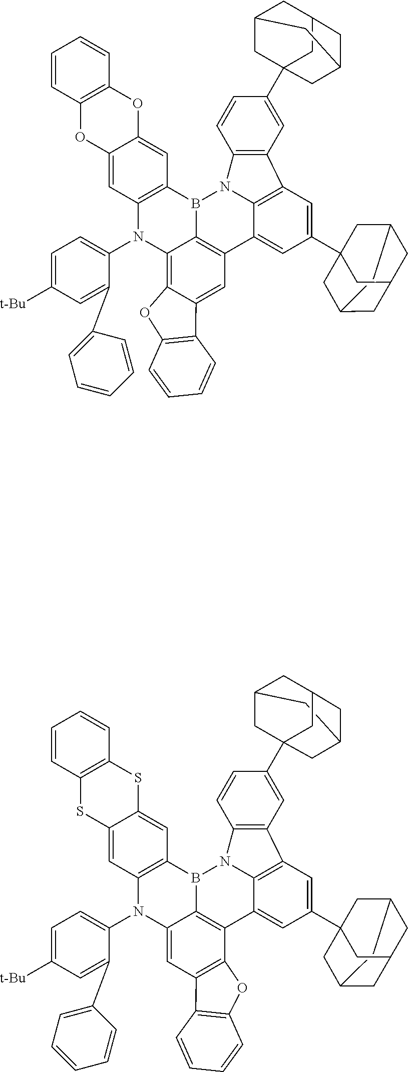 [SMILES: CC(C)(C)c1ccc(N2c3cc4c(cc3B3c5c(cc6c(oc7ccccc76)c52)-c2cc(C56CC7CC(CC(C7)C5)C6)cc5c6cc(C78CC9CC(CC(C9)C7)C8)ccc6n3c25)Oc2ccccc2O4)c(-c2ccccc2)c1 ; CC(C)(C)c1ccc(N2c3cc4c(cc3B3c5c2cc2c(oc6ccccc62)c5-c2cc(C56CC7CC(CC(C7)C5)C6)cc5c6cc(C78CC9CC(CC(C9)C7)C8)ccc6n3c25)Sc2ccccc2S4)c(-c2ccccc2)c1] 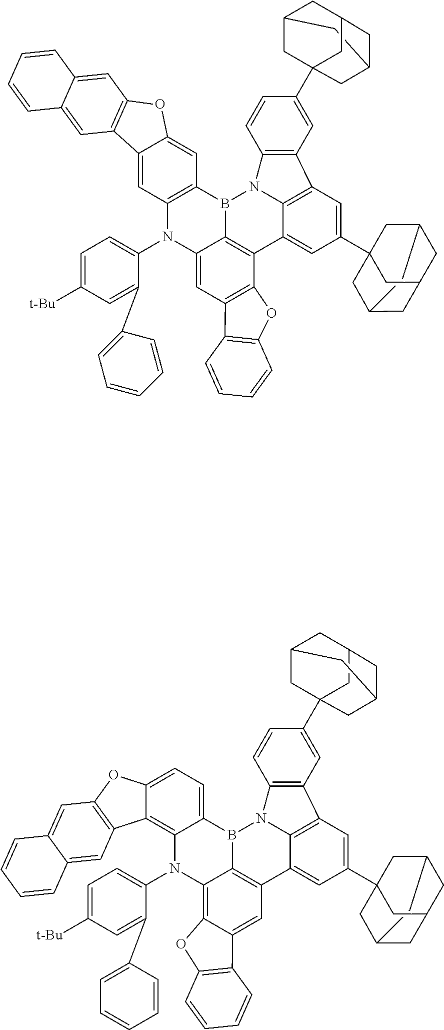 [SMILES: CC(C)(C)c1ccc(N2c3cc4c(cc3B3c5c2cc2c(oc6ccccc62)c5-c2cc(C56CC7CC(CC(C7)C5)C6)cc5c6cc(C78CC9CC(CC(C9)C7)C8)ccc6n3c25)oc2cc3ccccc3cc24)c(-c2ccccc2)c1 ; CC(C)(C)c1ccc(N2c3c4c(cc5c3oc3ccccc35)-c3cc(C56CC7CC(CC(C7)C5)C6)cc5c6cc(C78CC9CC(CC(C9)C7)C8)ccc6n(c35)B4c3ccc4oc5cc6ccccc6cc5c4c32)c(-c2ccccc2)c1] 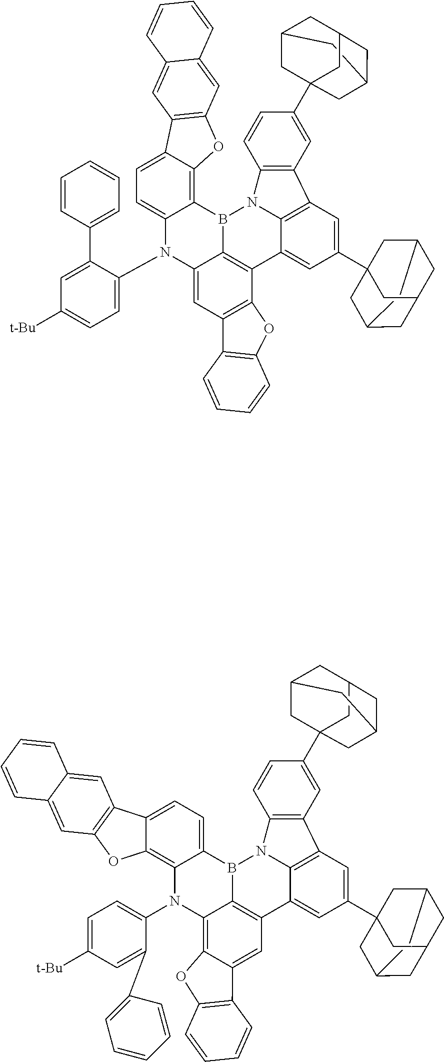 [SMILES: CC(C)(C)c1ccc(N2c3cc4c(oc5ccccc54)c4c3B(c3c2ccc2c3oc3cc5ccccc5cc32)n2c3ccc(C56CC7CC(CC(C7)C5)C6)cc3c3cc(C56CC7CC(CC(C7)C5)C6)cc-4c32)c(-c2ccccc2)c1 ; CC(C)(C)c1ccc(N2c3c(ccc4c3oc3cc5ccccc5cc34)B3c4c(cc5c(oc6ccccc65)c42)-c2cc(C45CC6CC(CC(C6)C4)C5)cc4c5cc(C67CC8CC(CC(C8)C6)C7)ccc5n3c24)c(-c2ccccc2)c1] 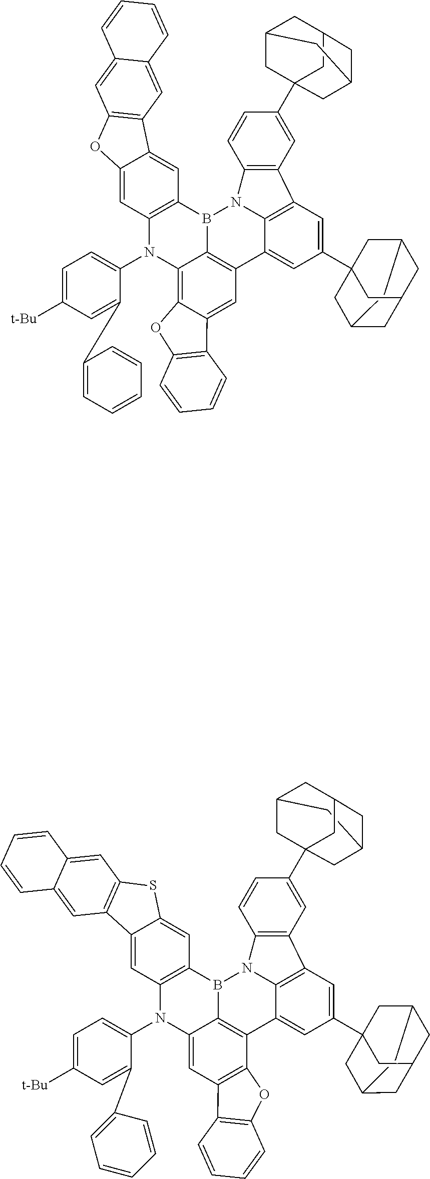 [SMILES: CC(C)(C)c1ccc(N2c3cc4oc5cc6ccccc6cc5c4cc3B3c4c(cc5c(oc6ccccc65)c42)-c2cc(C45CC6CC(CC(C6)C4)C5)cc4c5cc(C67CC8CC(CC(C8)C6)C7)ccc5n3c24)c(-c2ccccc2)c1 ; CC(C)(C)c1ccc(N2c3cc4c(cc3B3c5c2cc2c(oc6ccccc62)c5-c2cc(C56CC7CC(CC(C7)C5)C6)cc5c6cc(C78CC9CC(CC(C9)C7)C8)ccc6n3c25)sc2cc3ccccc3cc24)c(-c2ccccc2)c1] 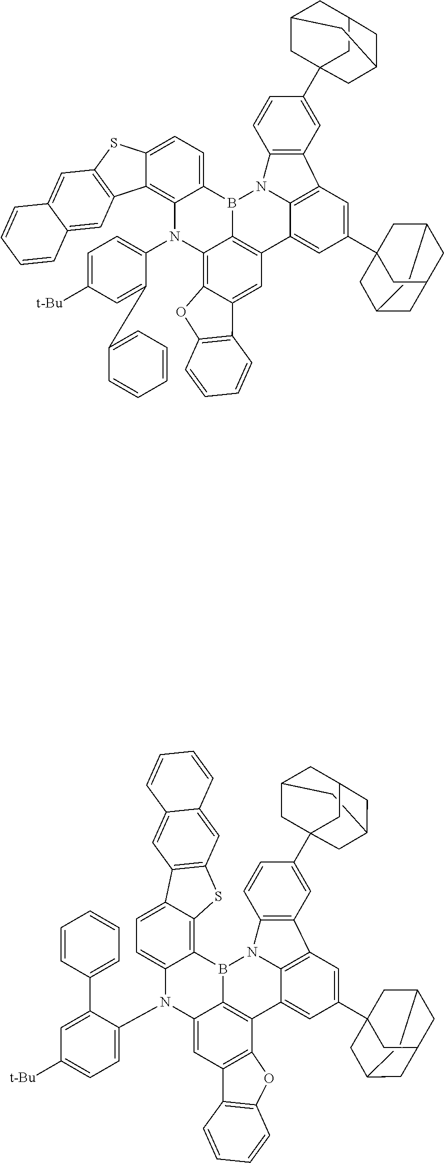 [SMILES: CC(C)(C)c1ccc(N2c3c4c(cc5c3oc3ccccc35)-c3cc(C56CC7CC(CC(C7)C5)C6)cc5c6cc(C78CC9CC(CC(C9)C7)C8)ccc6n(c35)B4c3ccc4sc5cc6ccccc6cc5c4c32)c(-c2ccccc2)c1 ; CC(C)(C)c1ccc(N2c3cc4c(oc5ccccc54)c4c3B(c3c2ccc2c3sc3cc5ccccc5cc32)n2c3ccc(C56CC7CC(CC(C7)C5)C6)cc3c3cc(C56CC7CC(CC(C7)C5)C6)cc-4c32)c(-c2ccccc2)c1] 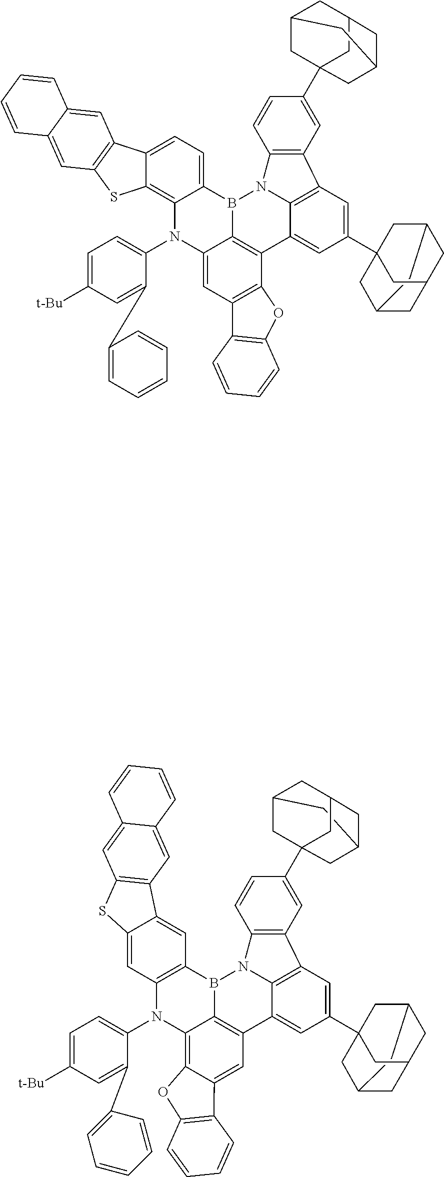 [SMILES: CC(C)(C)c1ccc(N2c3cc4c(oc5ccccc54)c4c3B(c3ccc5c(sc6cc7ccccc7cc65)c32)n2c3ccc(C56CC7CC(CC(C7)C5)C6)cc3c3cc(C56CC7CC(CC(C7)C5)C6)cc-4c32)c(-c2ccccc2)c1 ; CC(C)(C)c1ccc(N2c3cc4sc5cc6ccccc6cc5c4cc3B3c4c(cc5c(oc6ccccc65)c42)-c2cc(C45CC6CC(CC(C6)C4)C5)cc4c5cc(C67CC8CC(CC(C8)C6)C7)ccc5n3c24)c(-c2ccccc2)c1] 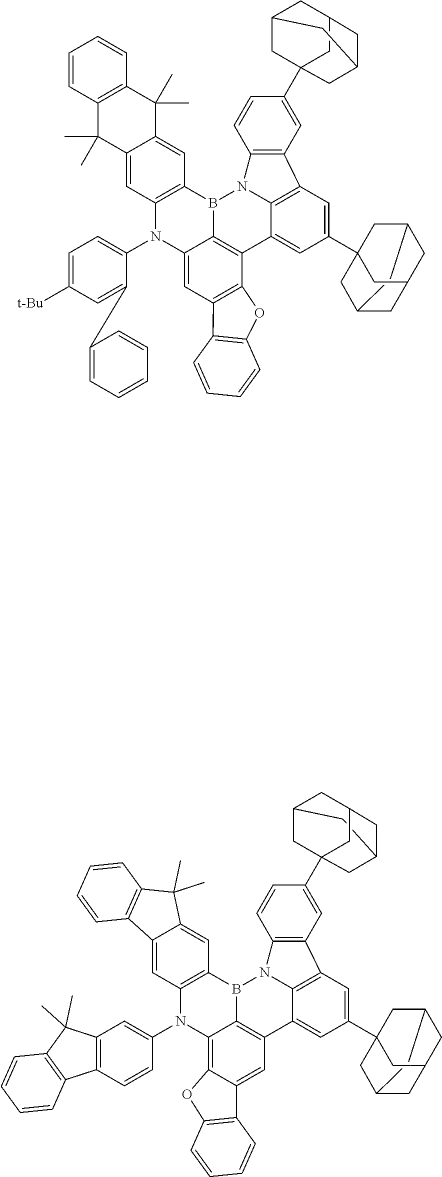 [SMILES: CC(C)(C)c1ccc(N2c3cc4c(cc3B3c5c2cc2c(oc6ccccc62)c5-c2cc(C56CC7CC(CC(C7)C5)C6)cc5c6cc(C78CC9CC(CC(C9)C7)C8)ccc6n3c25)C(C)(C)c2ccccc2C4(C)C)c(-c2ccccc2)c1 ; CC1(C)c2ccccc2-c2ccc(N3c4cc5c(cc4B4c6c(cc7c(oc8ccccc87)c63)-c3cc(C67CC8CC(CC(C8)C6)C7)cc6c7cc(C89CC%10CC(CC(C%10)C8)C9)ccc7n4c36)C(C)(C)c3ccccc3-5)cc21] 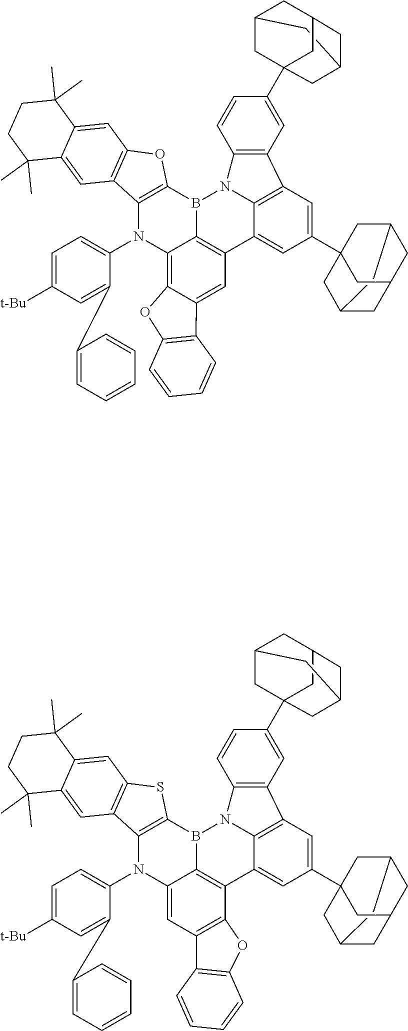 [SMILES: CC(C)(C)c1ccc(N2c3c(oc4cc5c(cc34)C(C)(C)CCC5(C)C)B3c4c(cc5c(oc6ccccc65)c42)-c2cc(C45CC6CC(CC(C6)C4)C5)cc4c5cc(C67CC8CC(CC(C8)C6)C7)ccc5n3c24)c(-c2ccccc2)c1 ; CC(C)(C)c1ccc(N2c3cc4c(oc5ccccc54)c4c3B(c3sc5cc6c(cc5c32)C(C)(C)CCC6(C)C)n2c3ccc(C56CC7CC(CC(C7)C5)C6)cc3c3cc(C56CC7CC(CC(C7)C5)C6)cc-4c32)c(-c2ccccc2)c1] 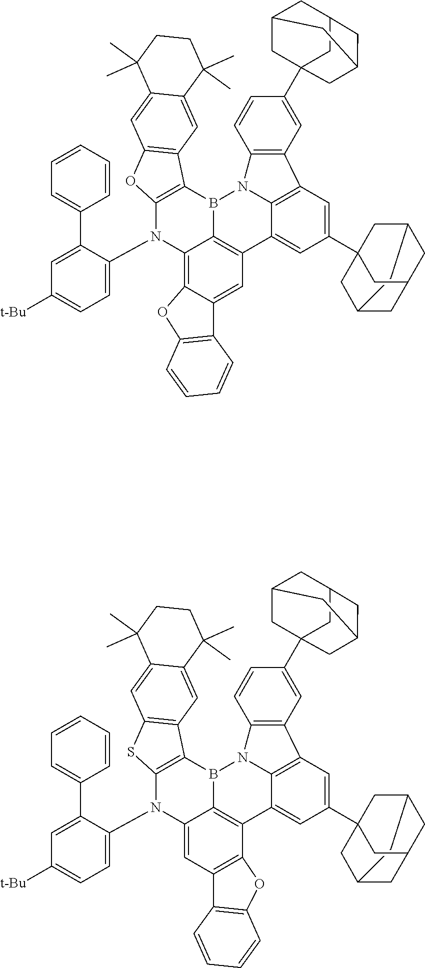 [SMILES: CC(C)(C)c1ccc(N2c3oc4cc5c(cc4c3B3c4c(cc6c(oc7ccccc76)c42)-c2cc(C46CC7CC(CC(C7)C4)C6)cc4c6cc(C78CC9CC(CC(C9)C7)C8)ccc6n3c24)C(C)(C)CCC5(C)C)c(-c2ccccc2)c1 ; CC(C)(C)c1ccc(N2c3cc4c(oc5ccccc54)c4c3B(c3c2sc2cc5c(cc32)C(C)(C)CCC5(C)C)n2c3ccc(C56CC7CC(CC(C7)C5)C6)cc3c3cc(C56CC7CC(CC(C7)C5)C6)cc-4c32)c(-c2ccccc2)c1] 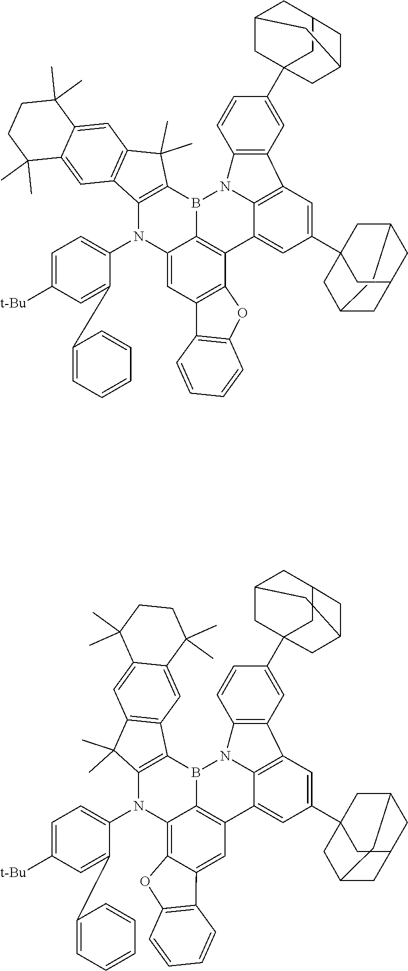 [SMILES: CC(C)(C)c1ccc(N2C3=C(B4c5c2cc2c(oc6ccccc62)c5-c2cc(C56CC7CC(CC(C7)C5)C6)cc5c6cc(C78CC9CC(CC(C9)C7)C8)ccc6n4c25)C(C)(C)c2cc4c(cc23)C(C)(C)CCC4(C)C)c(-c2ccccc2)c1 ; CC(C)(C)c1ccc(N2C3=C(B4c5c(cc6c(oc7ccccc76)c52)-c2cc(C56CC7CC(CC(C7)C5)C6)cc5c6cc(C78CC9CC(CC(C9)C7)C8)ccc6n4c25)c2cc4c(cc2C3(C)C)C(C)(C)CCC4(C)C)c(-c2ccccc2)c1] 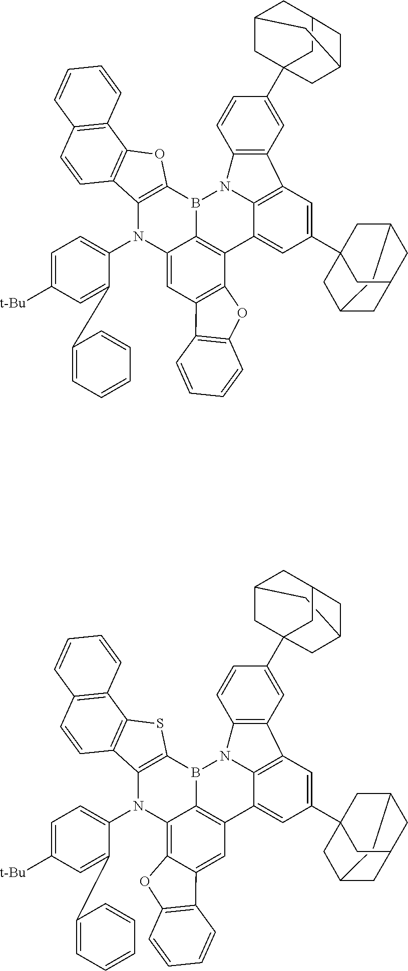 [SMILES: CC(C)(C)c1ccc(N2c3cc4c(oc5ccccc54)c4c3B(c3oc5c(ccc6ccccc65)c32)n2c3ccc(C56CC7CC(CC(C7)C5)C6)cc3c3cc(C56CC7CC(CC(C7)C5)C6)cc-4c32)c(-c2ccccc2)c1 ; CC(C)(C)c1ccc(N2c3c(sc4c3ccc3ccccc34)B3c4c(cc5c(oc6ccccc65)c42)-c2cc(C45CC6CC(CC(C6)C4)C5)cc4c5cc(C67CC8CC(CC(C8)C6)C7)ccc5n3c24)c(-c2ccccc2)c1] 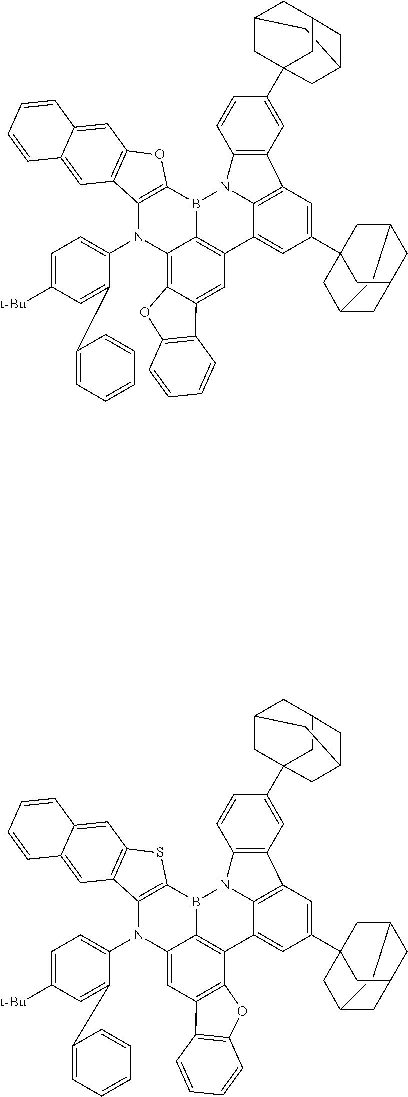 [SMILES: CC(C)(C)c1ccc(N2c3c(oc4cc5ccccc5cc34)B3c4c(cc5c(oc6ccccc65)c42)-c2cc(C45CC6CC(CC(C6)C4)C5)cc4c5cc(C67CC8CC(CC(C8)C6)C7)ccc5n3c24)c(-c2ccccc2)c1 ; CC(C)(C)c1ccc(N2c3cc4c(oc5ccccc54)c4c3B(c3sc5cc6ccccc6cc5c32)n2c3ccc(C56CC7CC(CC(C7)C5)C6)cc3c3cc(C56CC7CC(CC(C7)C5)C6)cc-4c32)c(-c2ccccc2)c1] 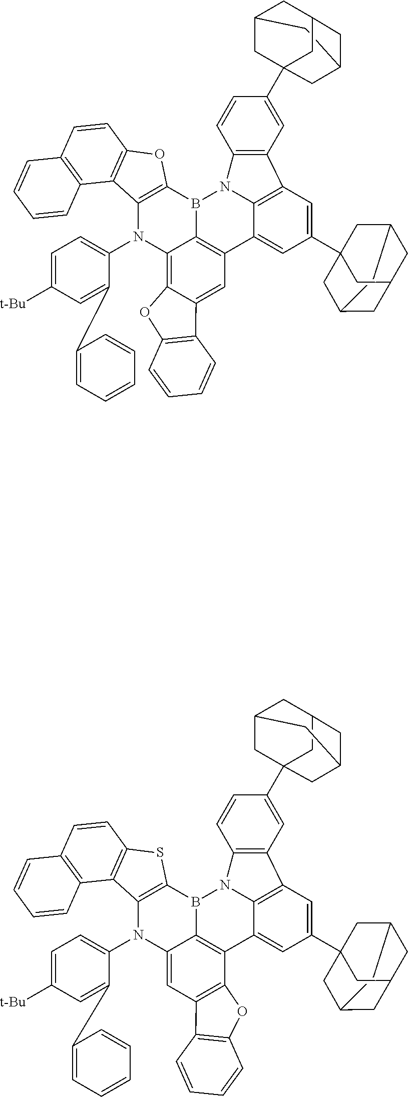 [SMILES: CC(C)(C)c1ccc(N2c3c4c(cc5c3oc3ccccc35)-c3cc(C56CC7CC(CC(C7)C5)C6)cc5c6cc(C78CC9CC(CC(C9)C7)C8)ccc6n(c35)B4c3oc4ccc5ccccc5c4c32)c(-c2ccccc2)c1 ; CC(C)(C)c1ccc(N2c3cc4c(oc5ccccc54)c4c3B(c3sc5ccc6ccccc6c5c32)n2c3ccc(C56CC7CC(CC(C7)C5)C6)cc3c3cc(C56CC7CC(CC(C7)C5)C6)cc-4c32)c(-c2ccccc2)c1] 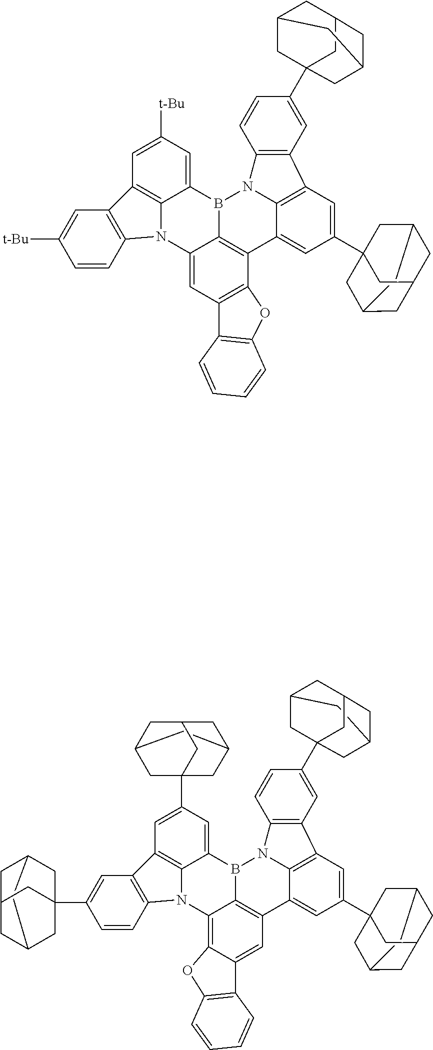 [SMILES: CC(C)(C)c1ccc2c(c1)c1cc(C(C)(C)C)cc3c1n2-c1cc2c(oc4ccccc42)c2c1B3n1c3ccc(C45CC6CC(CC(C6)C4)C5)cc3c3cc(C45CC6CC(CC(C6)C4)C5)cc-2c31 ; c1ccc2c(c1)oc1c3c4c(cc12)-c1cc(C25CC6CC(CC(C6)C2)C5)cc2c5cc(C67CC8CC(CC(C8)C6)C7)ccc5n(c12)B4c1cc(C24CC5CC(CC(C5)C2)C4)cc2c4cc(C56CC7CC(CC(C7)C5)C6)ccc4n-3c12] 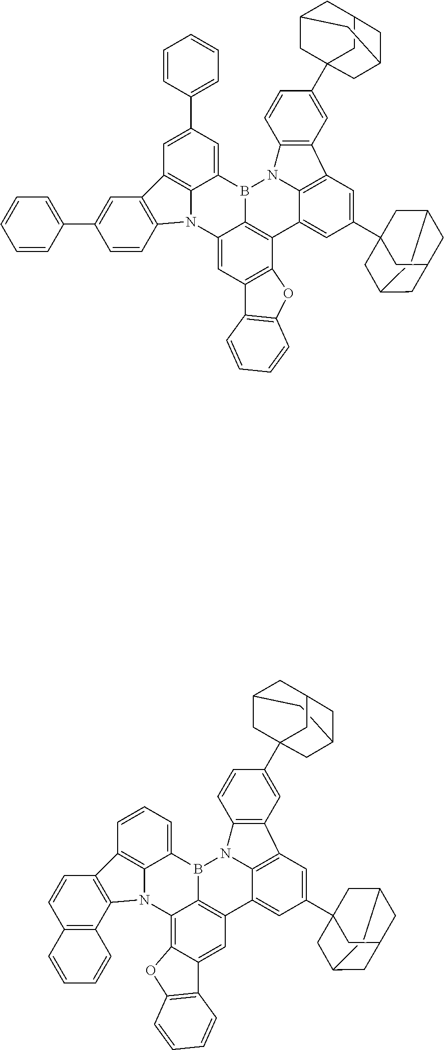 [SMILES: c1ccc(-c2ccc3c(c2)c2cc(-c4ccccc4)cc4c2n3-c2cc3c(oc5ccccc53)c3c2B4n2c4ccc(C56CC7CC(CC(C7)C5)C6)cc4c4cc(C56CC7CC(CC(C7)C5)C6)cc-3c42)cc1 ; c1ccc2c(c1)ccc1c3cccc4c3n(c21)-c1c2c(cc3c1oc1ccccc13)-c1cc(C35CC6CC(CC(C6)C3)C5)cc3c5cc(C67CC8CC(CC(C8)C6)C7)ccc5n(c13)B24] 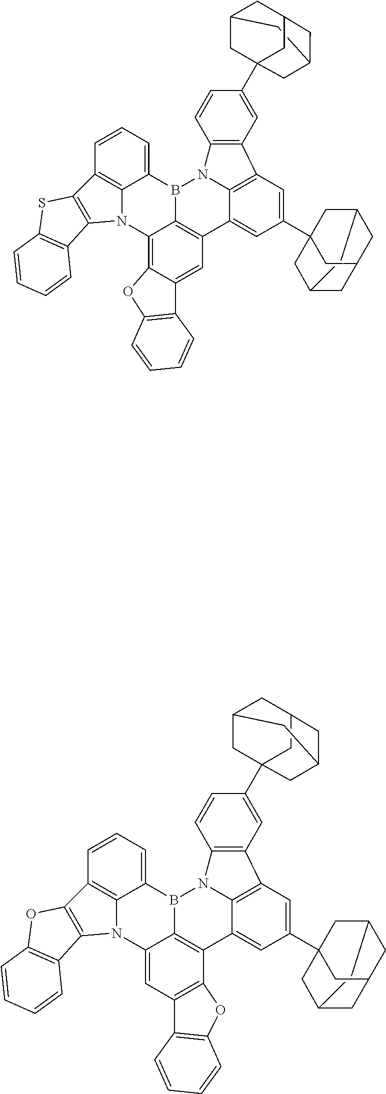 [SMILES: c1ccc2c(c1)oc1c3c4c(cc12)-c1cc(C25CC6CC(CC(C6)C2)C5)cc2c5cc(C67CC8CC(CC(C8)C6)C7)ccc5n(c12)B4c1cccc2c4sc5ccccc5c4n-3c12 ; c1ccc2c(c1)oc1c3c4c(cc12)-n1c2c(cccc2c2oc5ccccc5c21)B4n1c2ccc(C45CC6CC(CC(C6)C4)C5)cc2c2cc(C45CC6CC(CC(C6)C4)C5)cc-3c21] 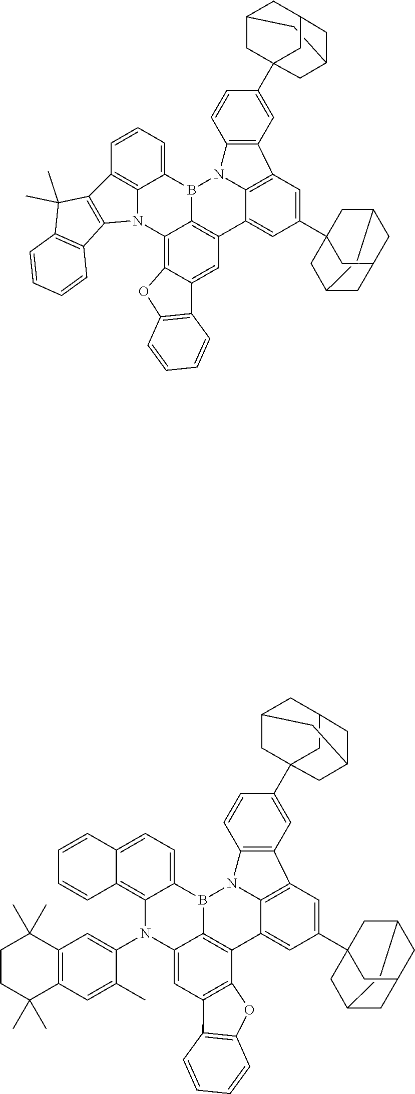 [SMILES: CC1(C)c2ccccc2-c2c1c1cccc3c1n2-c1c2c(cc4c1oc1ccccc14)-c1cc(C45CC6CC(CC(C6)C4)C5)cc4c5cc(C67CC8CC(CC(C8)C6)C7)ccc5n(c14)B23 ; Cc1cc2c(cc1N1c3cc4c(oc5ccccc54)c4c3B(c3ccc5ccccc5c31)n1c3ccc(C56CC7CC(CC(C7)C5)C6)cc3c3cc(C56CC7CC(CC(C7)C5)C6)cc-4c31)C(C)(C)CCC2(C)C] 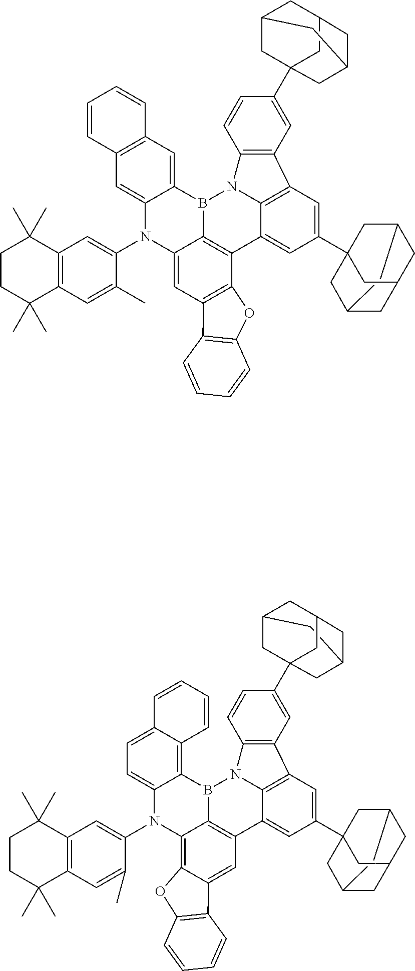 [SMILES: Cc1cc2c(cc1N1c3cc4ccccc4cc3B3c4c1cc1c(oc5ccccc51)c4-c1cc(C45CC6CC(CC(C6)C4)C5)cc4c5cc(C67CC8CC(CC(C8)C6)C7)ccc5n3c14)C(C)(C)CCC2(C)C ; Cc1cc2c(cc1N1c3ccc4ccccc4c3B3c4c(cc5c(oc6ccccc65)c41)-c1cc(C45CC6CC(CC(C6)C4)C5)cc4c5cc(C67CC8CC(CC(C8)C6)C7)ccc5n3c14)C(C)(C)CCC2(C)C] 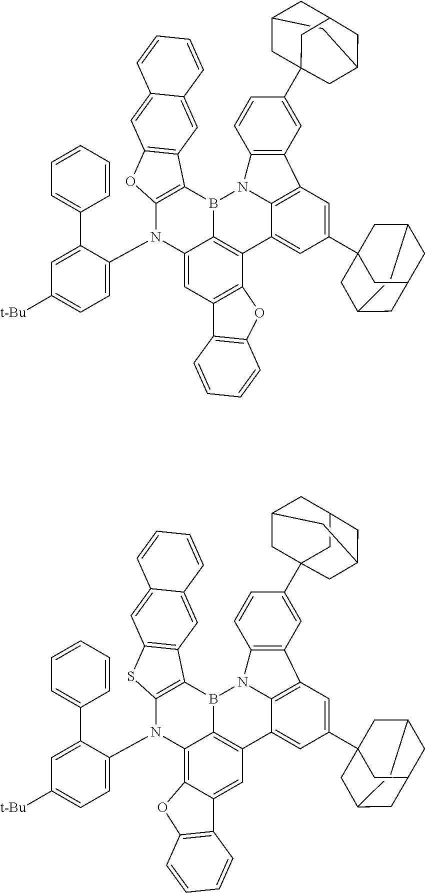 [SMILES: CC(C)(C)c1ccc(N2c3cc4c(oc5ccccc54)c4c3B(c3c2oc2cc5ccccc5cc32)n2c3ccc(C56CC7CC(CC(C7)C5)C6)cc3c3cc(C56CC7CC(CC(C7)C5)C6)cc-4c32)c(-c2ccccc2)c1 ; CC(C)(C)c1ccc(N2c3sc4cc5ccccc5cc4c3B3c4c(cc5c(oc6ccccc65)c42)-c2cc(C45CC6CC(CC(C6)C4)C5)cc4c5cc(C67CC8CC(CC(C8)C6)C7)ccc5n3c24)c(-c2ccccc2)c1] 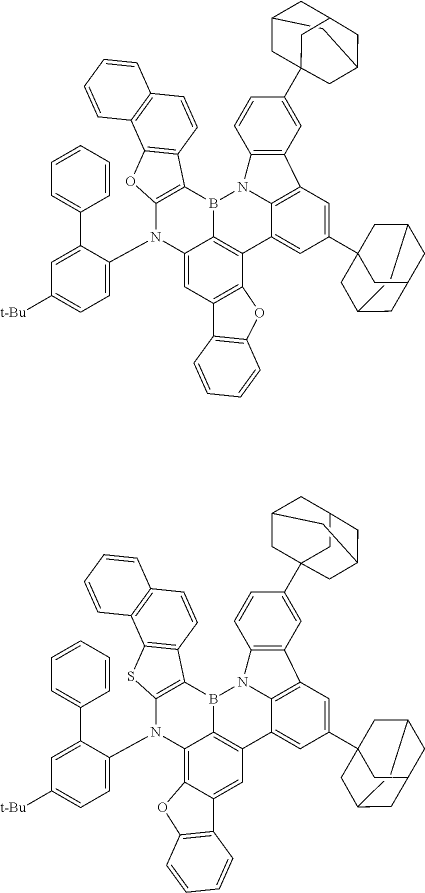 [SMILES: CC(C)(C)c1ccc(N2c3cc4c(oc5ccccc54)c4c3B(c3c2oc2c3ccc3ccccc32)n2c3ccc(C56CC7CC(CC(C7)C5)C6)cc3c3cc(C56CC7CC(CC(C7)C5)C6)cc-4c32)c(-c2ccccc2)c1 ; CC(C)(C)c1ccc(N2c3sc4c(ccc5ccccc54)c3B3c4c(cc5c(oc6ccccc65)c42)-c2cc(C45CC6CC(CC(C6)C4)C5)cc4c5cc(C67CC8CC(CC(C8)C6)C7)ccc5n3c24)c(-c2ccccc2)c1] 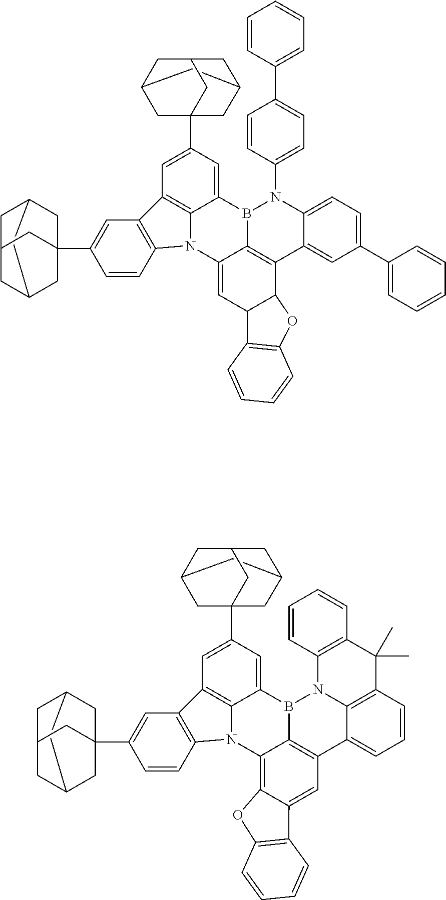 [SMILES: C1=C2C3=C(c4cc(-c5ccccc5)ccc4N(c4ccc(-c5ccccc5)cc4)B3c3cc(C45CC6CC(CC(C6)C4)C5)cc4c5cc(C67CC8CC(CC(C8)C6)C7)ccc5n2c34)C2Oc3ccccc3C12 ; CC1(C)c2ccccc2N2B3c4c(cc5c(oc6ccccc65)c4-n4c5ccc(C67CC8CC(CC(C8)C6)C7)cc5c5cc(C67CC8CC(CC(C8)C6)C7)cc3c54)-c3cccc1c32] 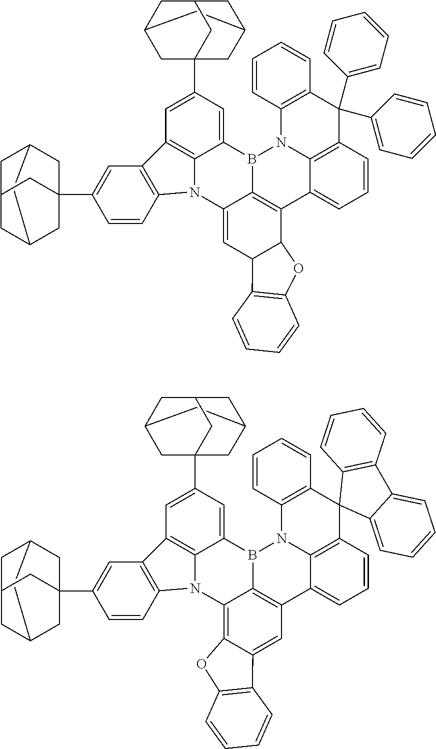 [SMILES: C1=C2C3=C(c4cccc5c4N(B3c3cc(C46CC7CC(CC(C7)C4)C6)cc4c6cc(C78CC9CC(CC(C9)C7)C8)ccc6n2c34)c2ccccc2C5(c2ccccc2)c2ccccc2)C2Oc3ccccc3C12 ; c1ccc2c(c1)-c1ccccc1C21c2ccccc2N2B3c4c(cc5c(oc6ccccc65)c4-n4c5ccc(C67CC8CC(CC(C8)C6)C7)cc5c5cc(C67CC8CC(CC(C8)C6)C7)cc3c54)-c3cccc1c32] 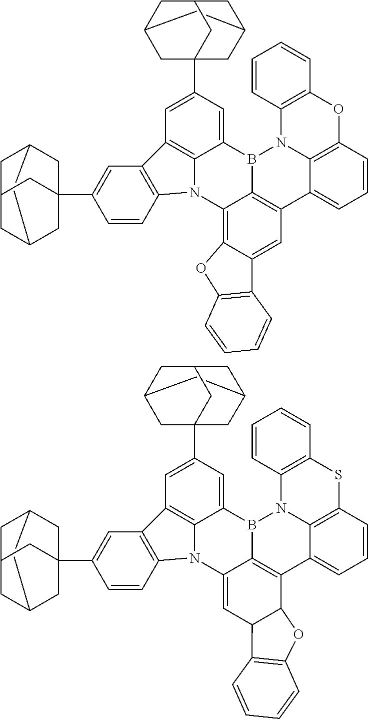 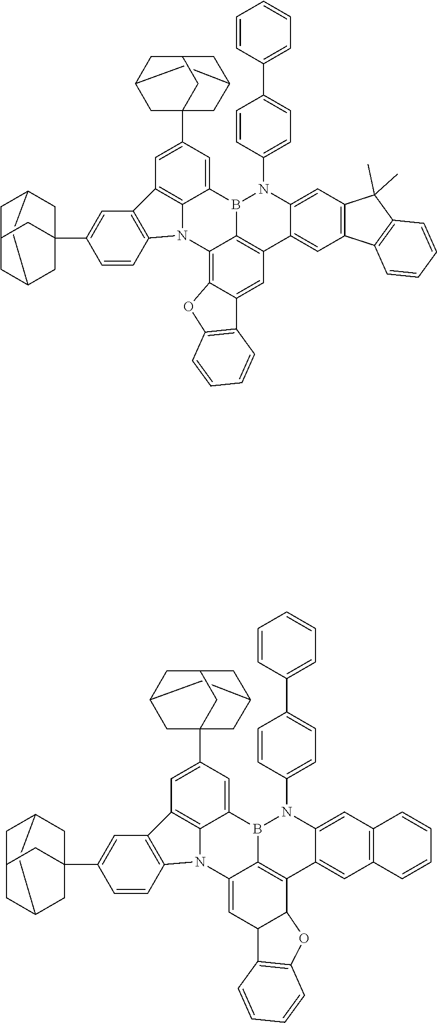 [SMILES: CC1(C)c2ccccc2-c2cc3c(cc21)N(c1ccc(-c2ccccc2)cc1)B1c2c-3cc3c(oc4ccccc43)c2-n2c3ccc(C45CC6CC(CC(C6)C4)C5)cc3c3cc(C45CC6CC(CC(C6)C4)C5)cc1c32 ; C1=C2C3=C(c4cc5ccccc5cc4N(c4ccc(-c5ccccc5)cc4)B3c3cc(C45CC6CC(CC(C6)C4)C5)cc4c5cc(C67CC8CC(CC(C8)C6)C7)ccc5n2c34)C2Oc3ccccc3C12] 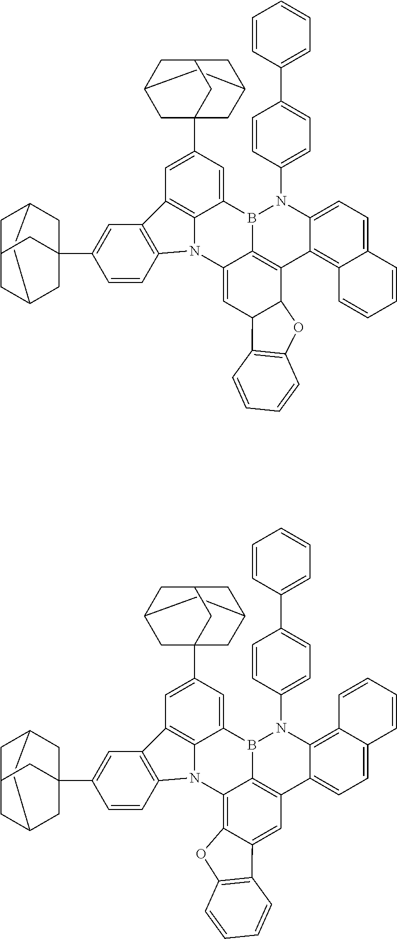 [SMILES: C1=C2C3=C(c4c(ccc5ccccc45)N(c4ccc(-c5ccccc5)cc4)B3c3cc(C45CC6CC(CC(C6)C4)C5)cc4c5cc(C67CC8CC(CC(C8)C6)C7)ccc5n2c34)C2Oc3ccccc3C12 ; c1ccc(-c2ccc(N3B4c5c(cc6c(oc7ccccc76)c5-n5c6ccc(C78CC9CC(CC(C9)C7)C8)cc6c6cc(C78CC9CC(CC(C9)C7)C8)cc4c65)-c4ccc5ccccc5c43)cc2)cc1] 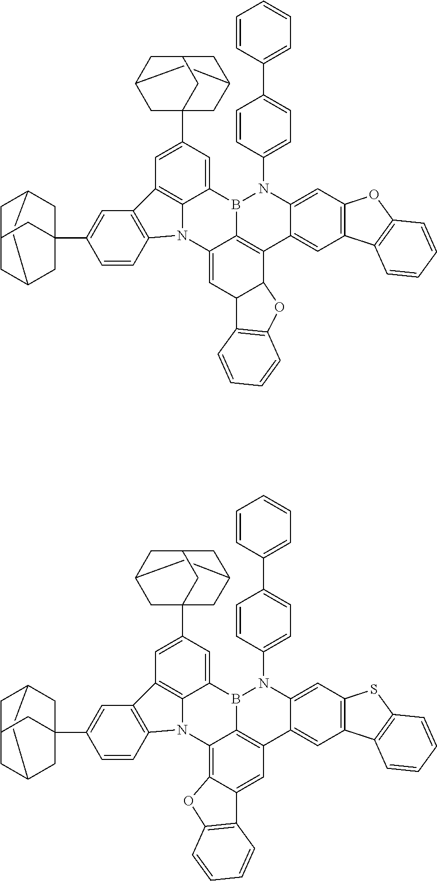 [SMILES: C1=C2C3=C(c4cc5c(cc4N(c4ccc(-c6ccccc6)cc4)B3c3cc(C46CC7CC(CC(C7)C4)C6)cc4c6cc(C78CC9CC(CC(C9)C7)C8)ccc6n2c34)oc2ccccc25)C2Oc3ccccc3C12 ; c1ccc(-c2ccc(N3B4c5c(cc6c(oc7ccccc76)c5-n5c6ccc(C78CC9CC(CC(C9)C7)C8)cc6c6cc(C78CC9CC(CC(C9)C7)C8)cc4c65)-c4cc5c(cc43)sc3ccccc35)cc2)cc1] 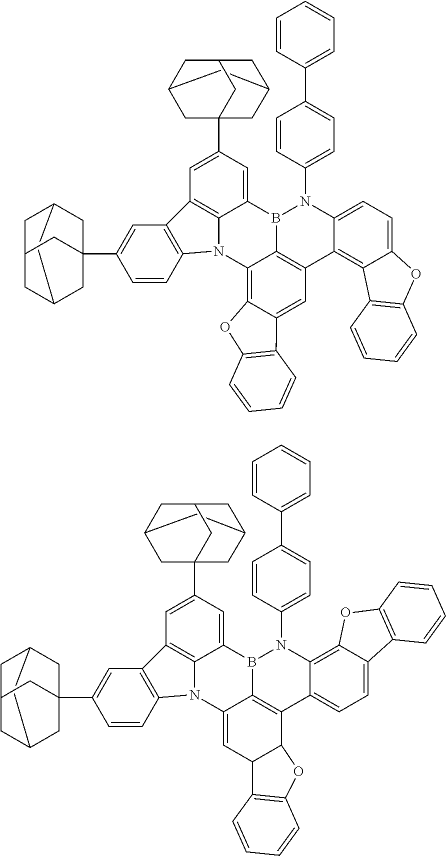 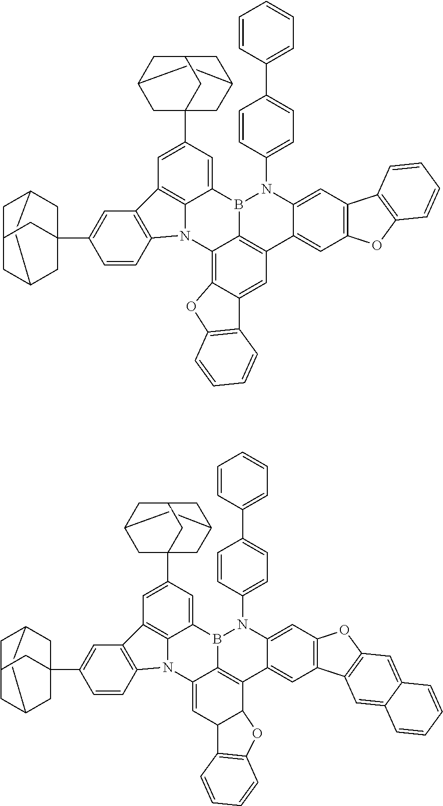 [SMILES: c1ccc(-c2ccc(N3B4c5c(cc6c(oc7ccccc76)c5-n5c6ccc(C78CC9CC(CC(C9)C7)C8)cc6c6cc(C78CC9CC(CC(C9)C7)C8)cc4c65)-c4cc5oc6ccccc6c5cc43)cc2)cc1 ; C1=C2C3=C(c4cc5c(cc4N(c4ccc(-c6ccccc6)cc4)B3c3cc(C46CC7CC(CC(C7)C4)C6)cc4c6cc(C78CC9CC(CC(C9)C7)C8)ccc6n2c34)oc2cc3ccccc3cc25)C2Oc3ccccc3C12] 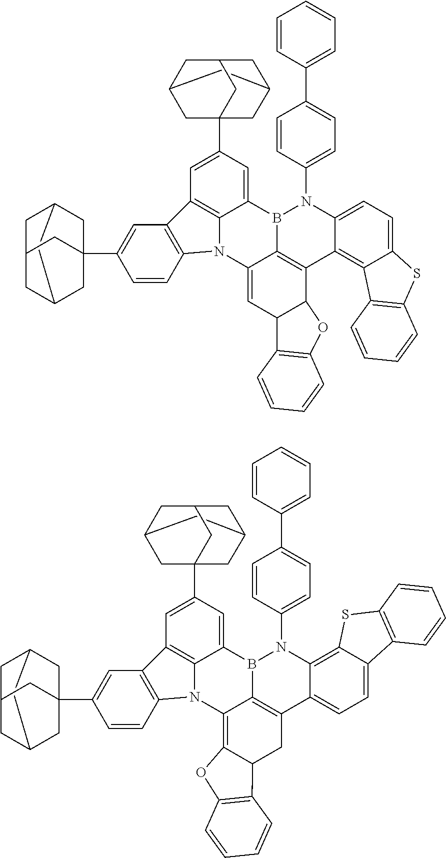 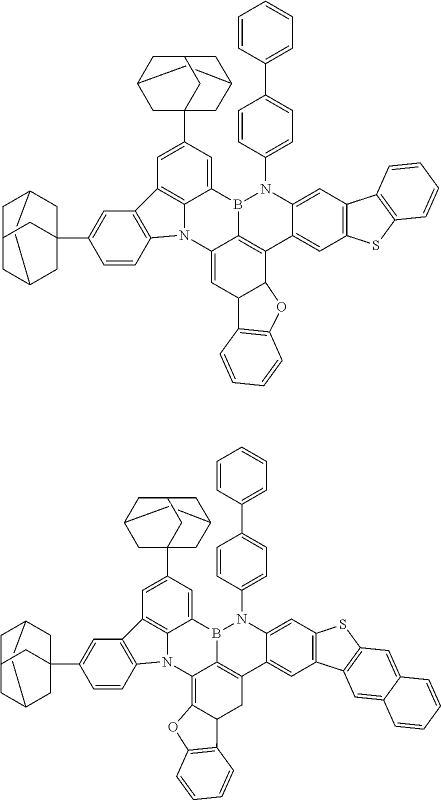 [SMILES: C1=C2C3=C(c4cc5sc6ccccc6c5cc4N(c4ccc(-c5ccccc5)cc4)B3c3cc(C45CC6CC(CC(C6)C4)C5)cc4c5cc(C67CC8CC(CC(C8)C6)C7)ccc5n2c34)C2Oc3ccccc3C12 ; c1ccc(-c2ccc(N3B4C5=C(CC6C(=C5n5c7ccc(C89CC%10CC(CC(C%10)C8)C9)cc7c7cc(C89CC%10CC(CC(C%10)C8)C9)cc4c75)Oc4ccccc46)c4cc5c(cc43)sc3cc4ccccc4cc35)cc2)cc1] 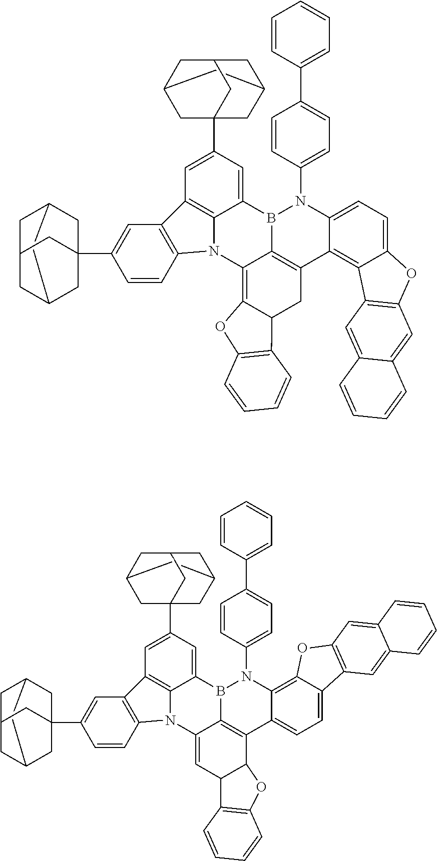 [SMILES: c1ccc(-c2ccc(N3B4C5=C(CC6C(=C5n5c7ccc(C89CC%10CC(CC(C%10)C8)C9)cc7c7cc(C89CC%10CC(CC(C%10)C8)C9)cc4c75)Oc4ccccc46)c4c3ccc3oc5cc6ccccc6cc5c43)cc2)cc1 ; C1=C2C3=C(c4ccc5c(oc6cc7ccccc7cc65)c4N(c4ccc(-c5ccccc5)cc4)B3c3cc(C45CC6CC(CC(C6)C4)C5)cc4c5cc(C67CC8CC(CC(C8)C6)C7)ccc5n2c34)C2Oc3ccccc3C12] 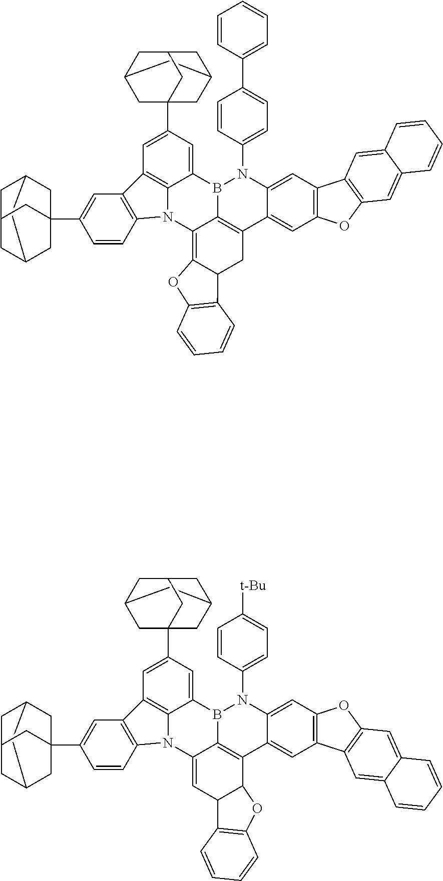 [SMILES: c1ccc(-c2ccc(N3B4C5=C(CC6C(=C5n5c7ccc(C89CC%10CC(CC(C%10)C8)C9)cc7c7cc(C89CC%10CC(CC(C%10)C8)C9)cc4c75)Oc4ccccc46)c4cc5oc6cc7ccccc7cc6c5cc43)cc2)cc1 ; CC(C)(C)c1ccc(N2B3C4=C(c5cc6c(cc52)oc2cc5ccccc5cc26)C2Oc5ccccc5C2C=C4n2c4ccc(C56CC7CC(CC(C7)C5)C6)cc4c4cc(C56CC7CC(CC(C7)C5)C6)cc3c42)cc1] 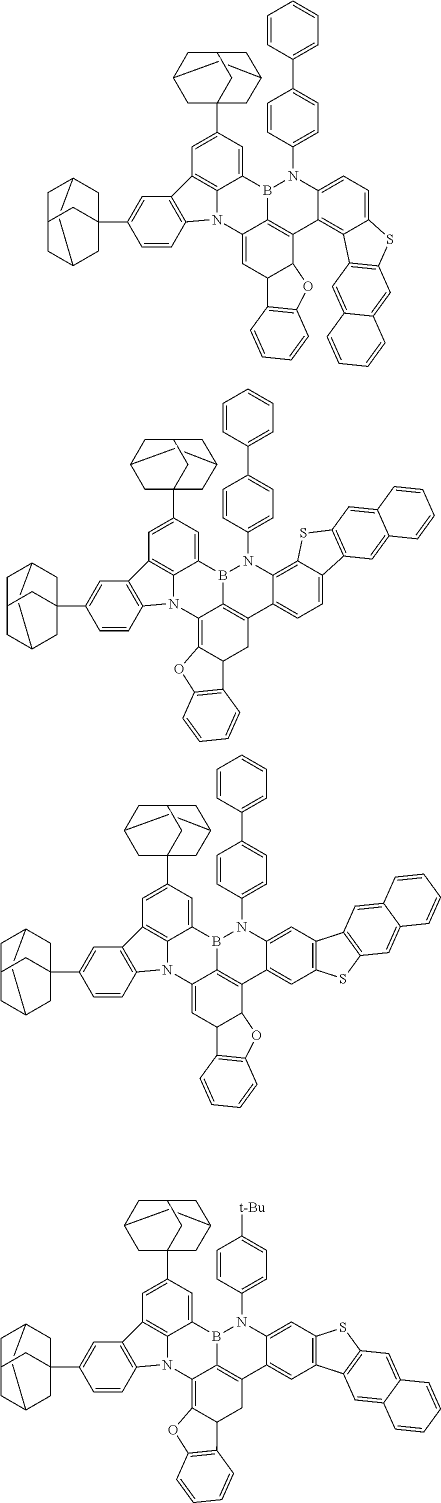 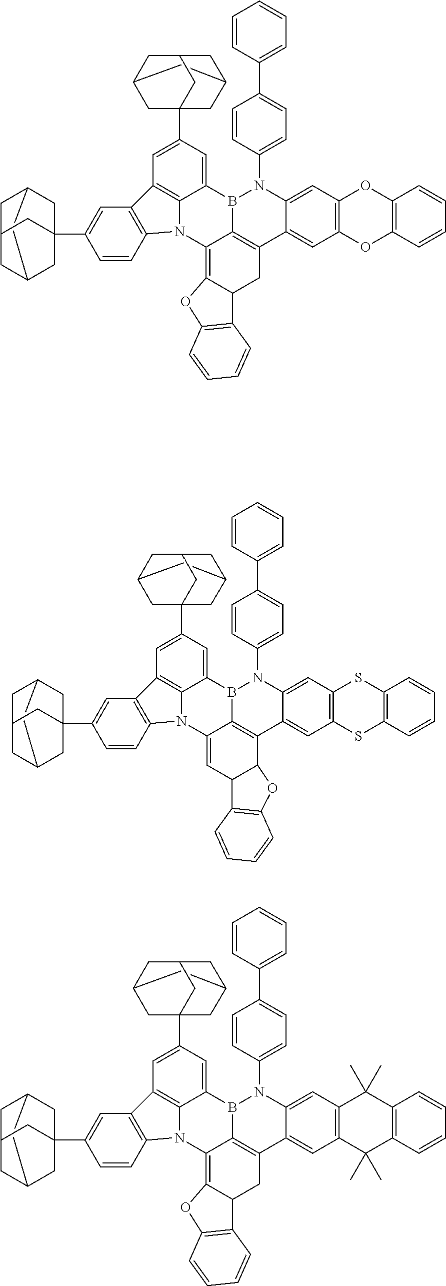 [SMILES: c1ccc(-c2ccc(N3B4C5=C(CC6C(=C5n5c7ccc(C89CC%10CC(CC(C%10)C8)C9)cc7c7cc(C89CC%10CC(CC(C%10)C8)C9)cc4c75)Oc4ccccc46)c4cc5c(cc43)Oc3ccccc3O5)cc2)cc1 ; C1=C2C3=C(c4cc5c(cc4N(c4ccc(-c6ccccc6)cc4)B3c3cc(C46CC7CC(CC(C7)C4)C6)cc4c6cc(C78CC9CC(CC(C9)C7)C8)ccc6n2c34)Sc2ccccc2S5)C2Oc3ccccc3C12 ; CC1(C)c2ccccc2C(C)(C)c2cc3c(cc21)C1=C2B(c4cc(C56CC7CC(CC(C7)C5)C6)cc5c6cc(C78CC9CC(CC(C9)C7)C8)ccc6n(c45)C2=C2Oc4ccccc4C2C1)N3c1ccc(-c2ccccc2)cc1] 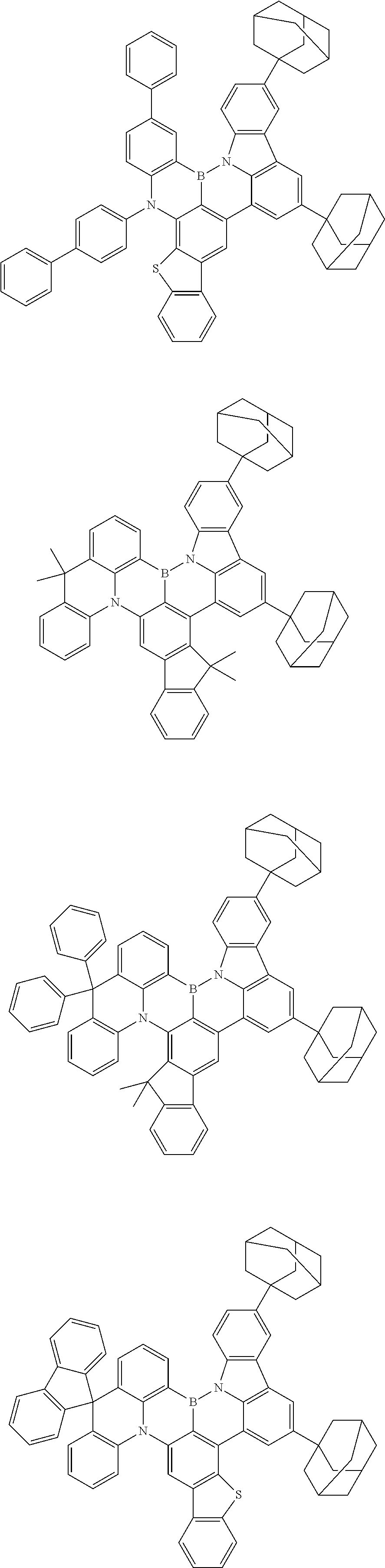 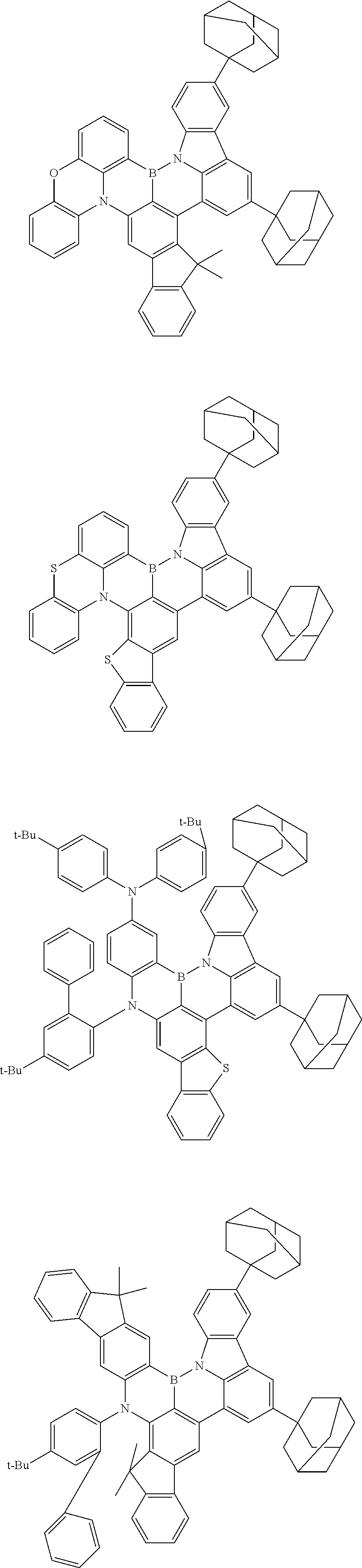 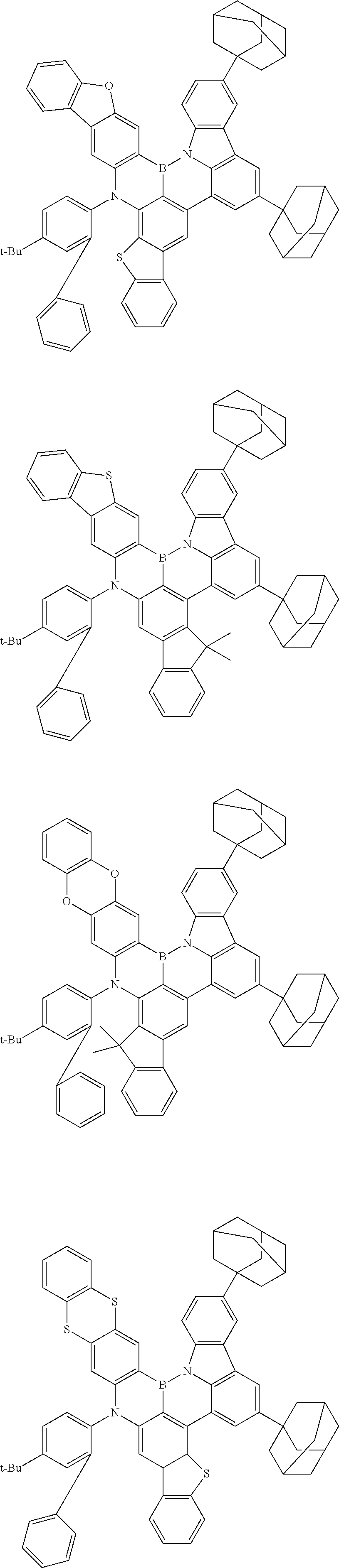 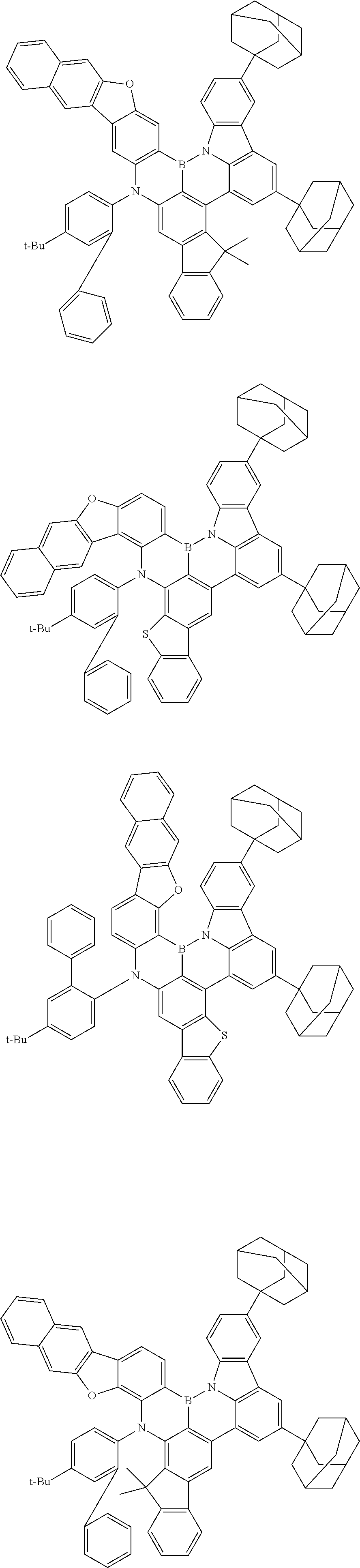 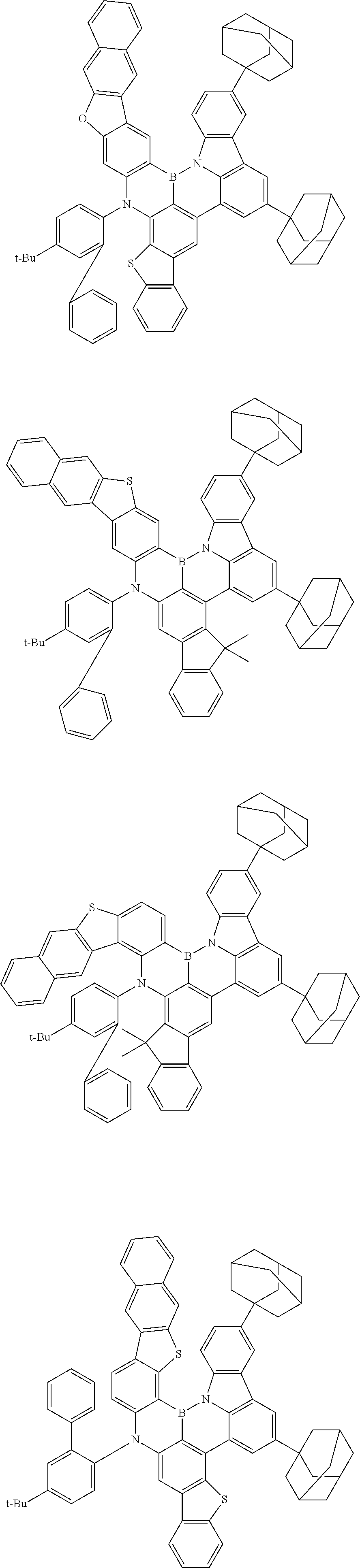 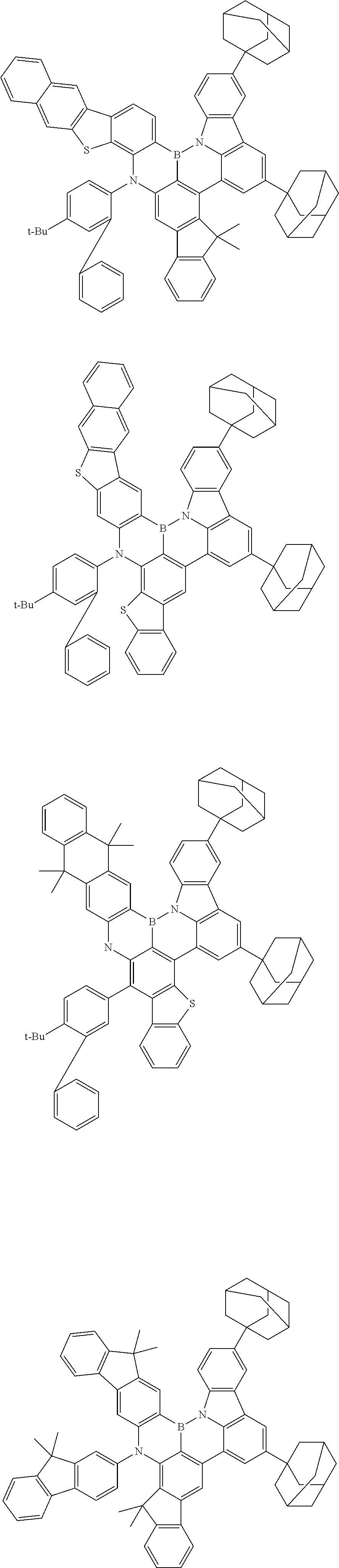 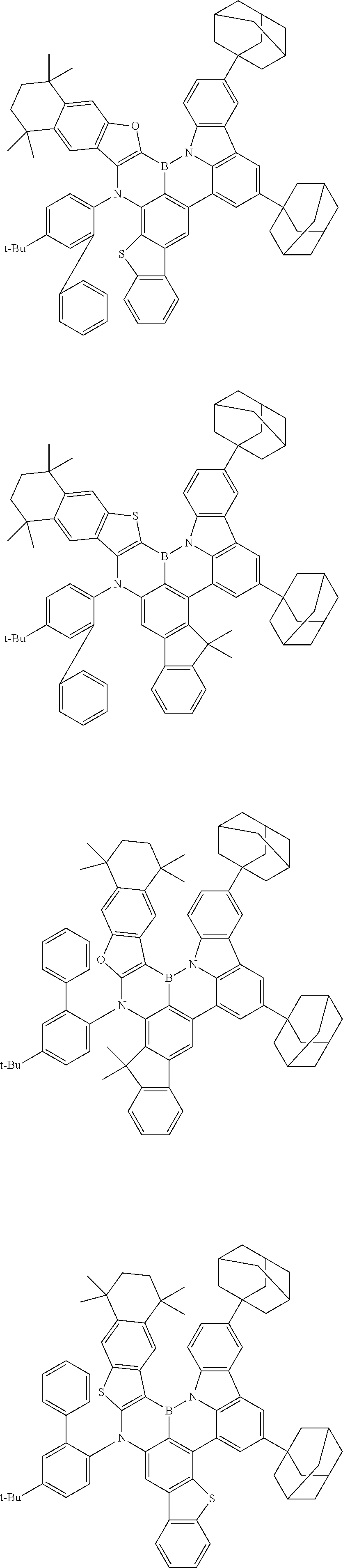 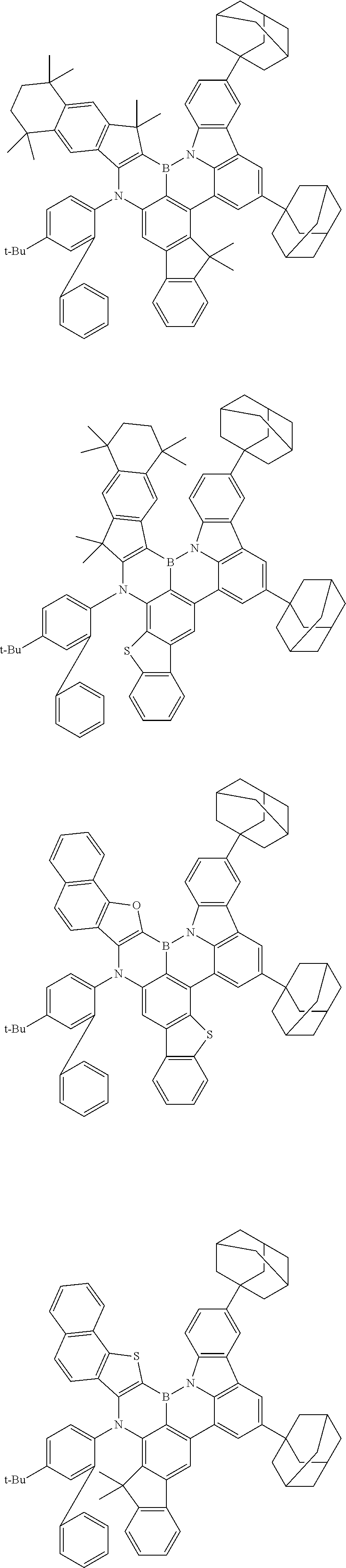 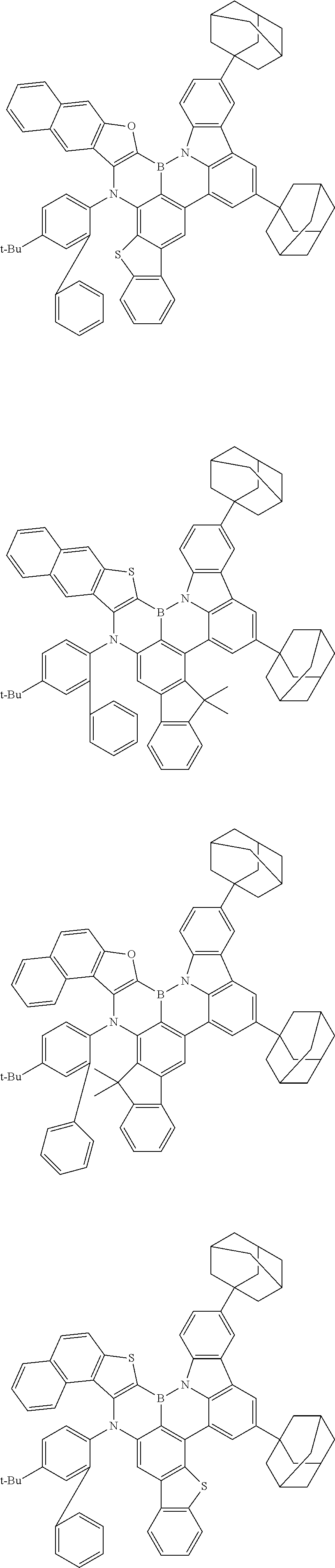 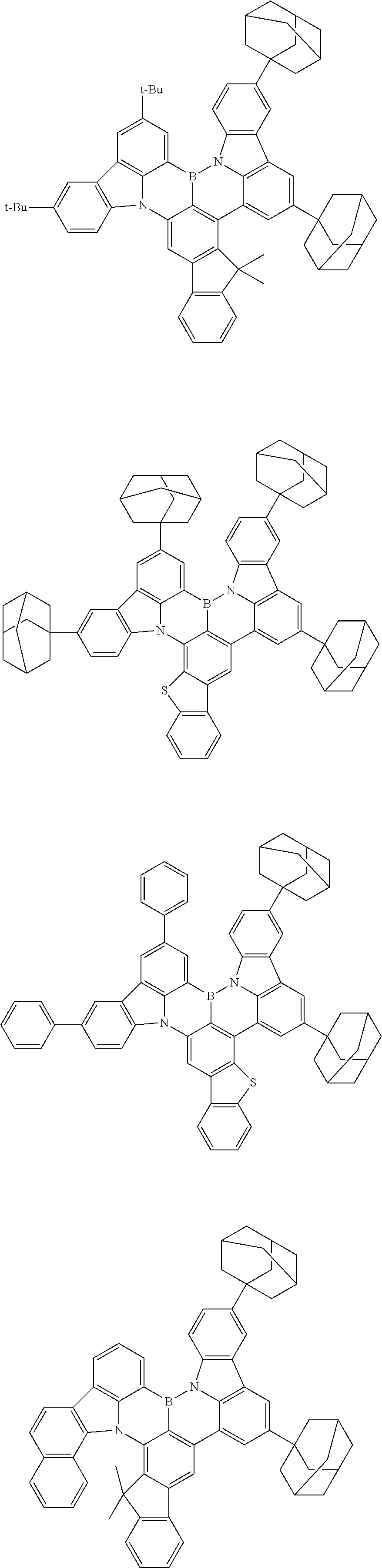 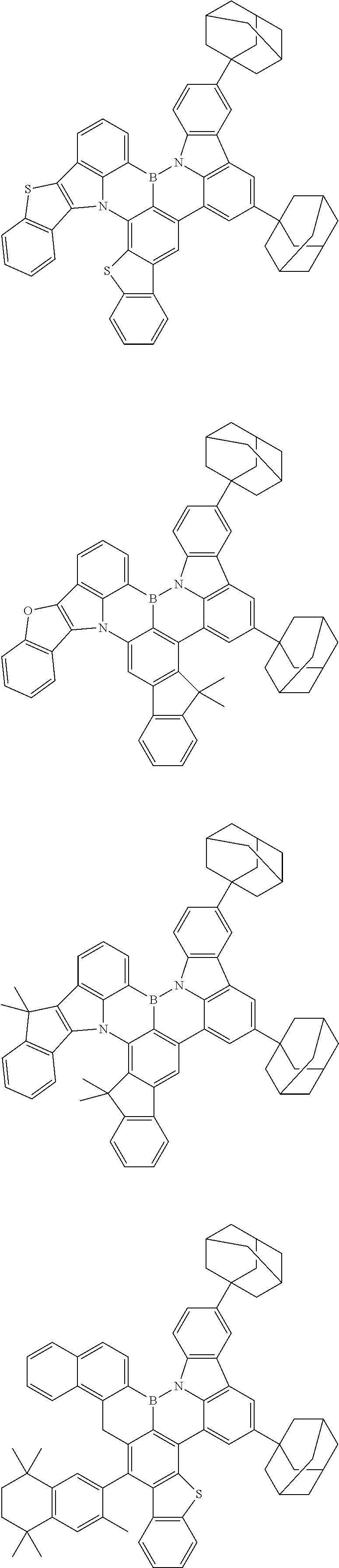 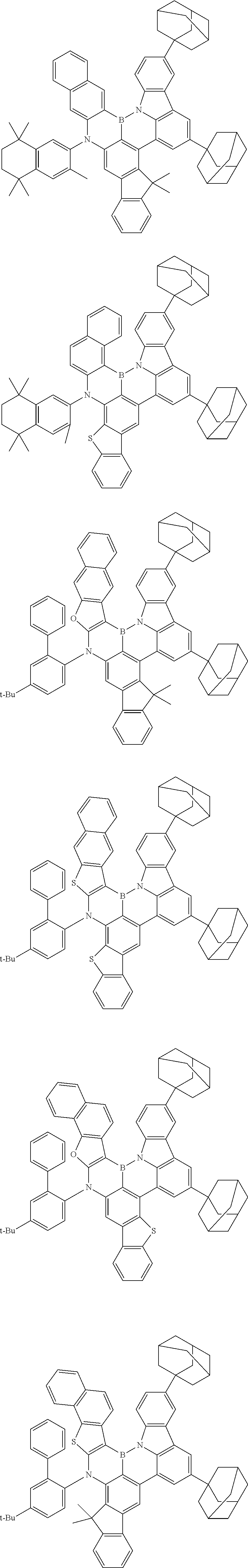 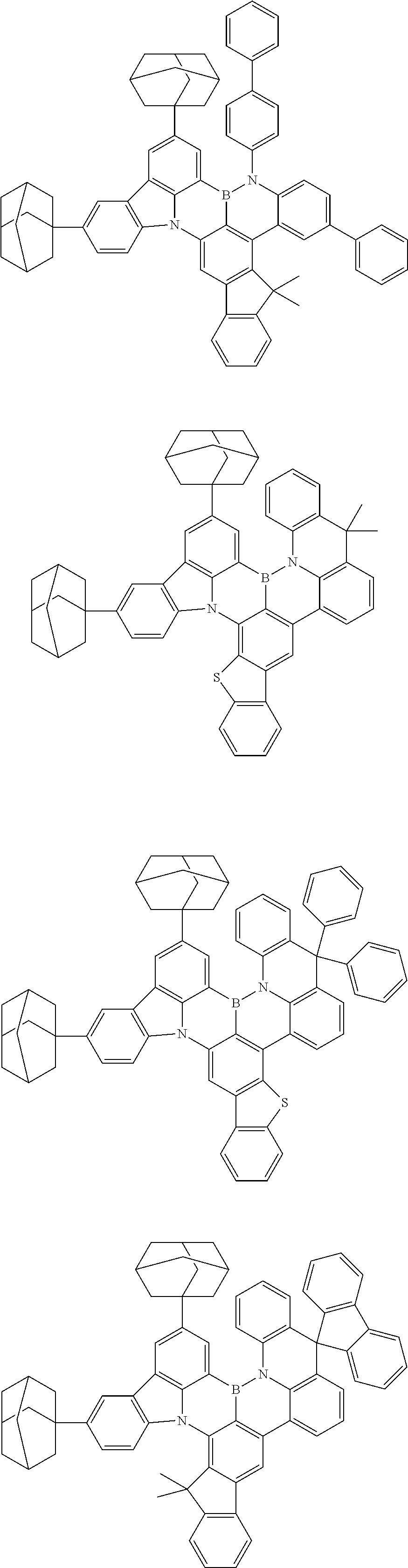 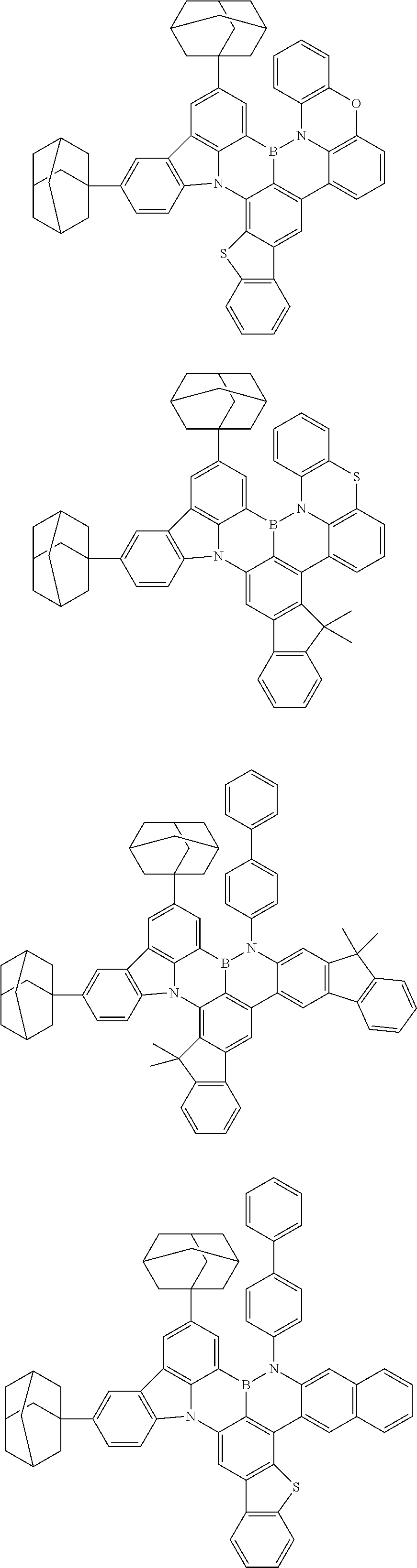 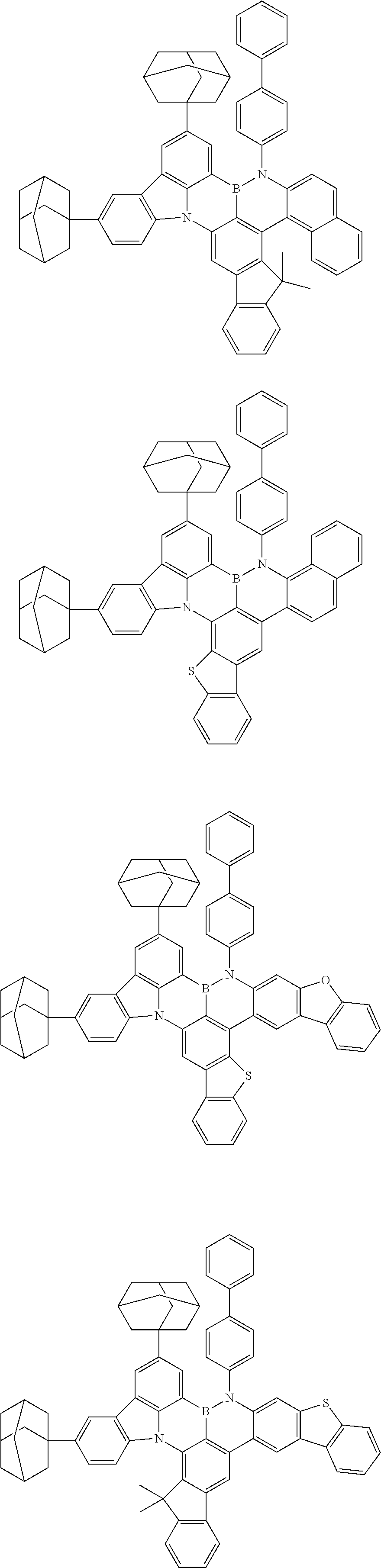 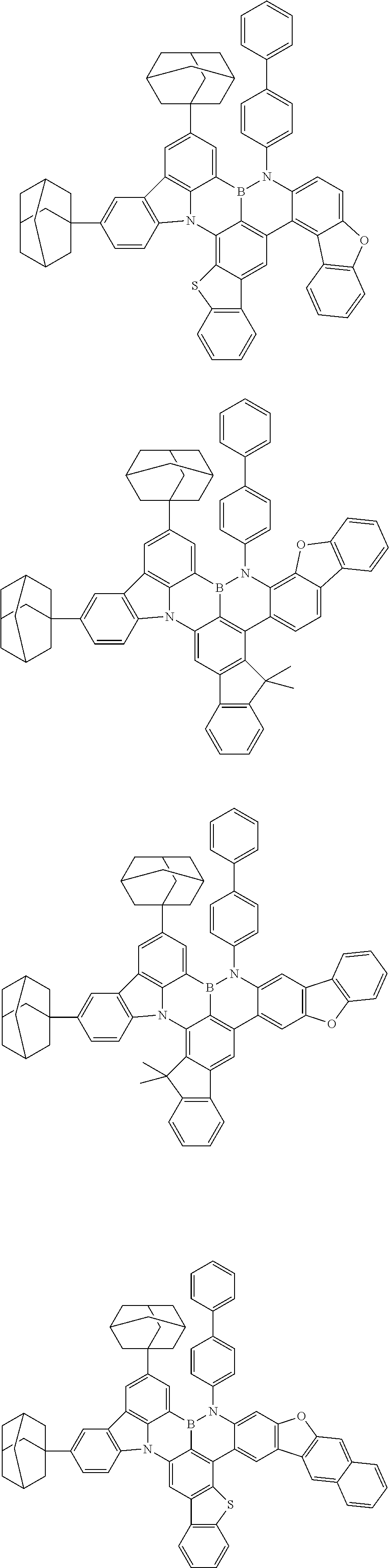 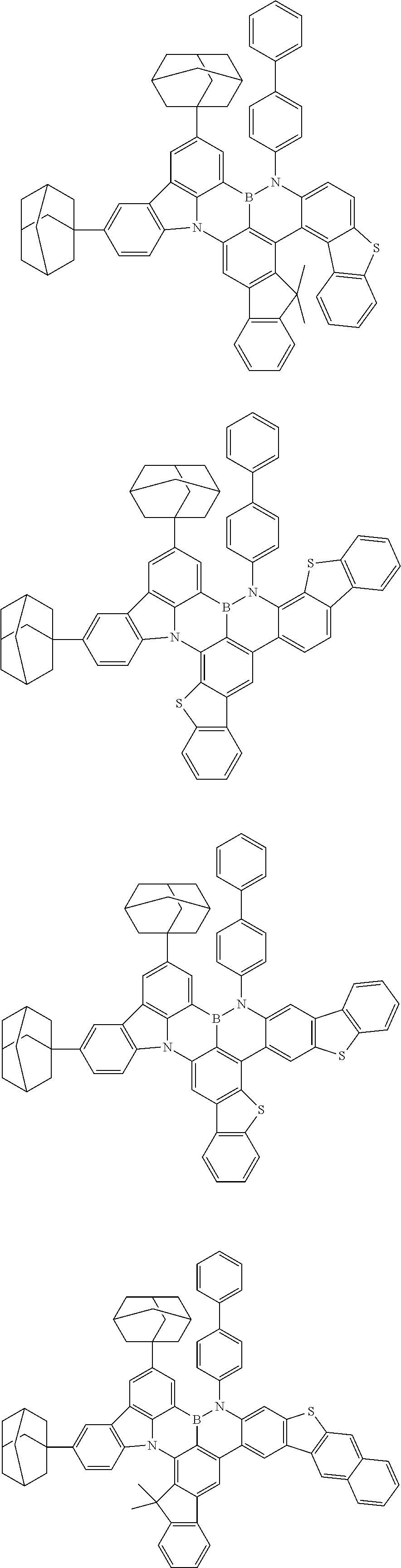 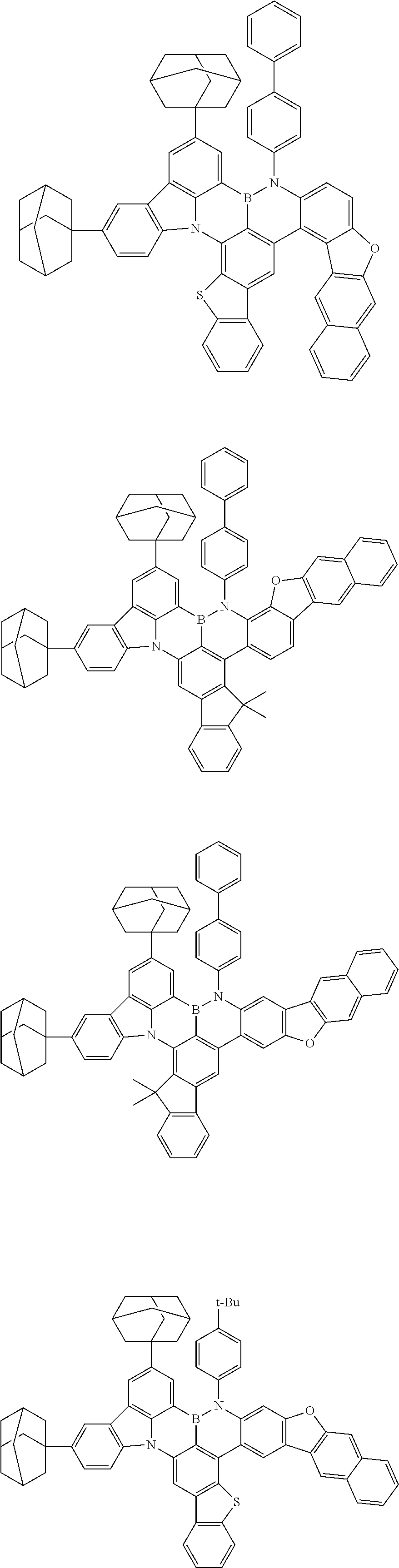 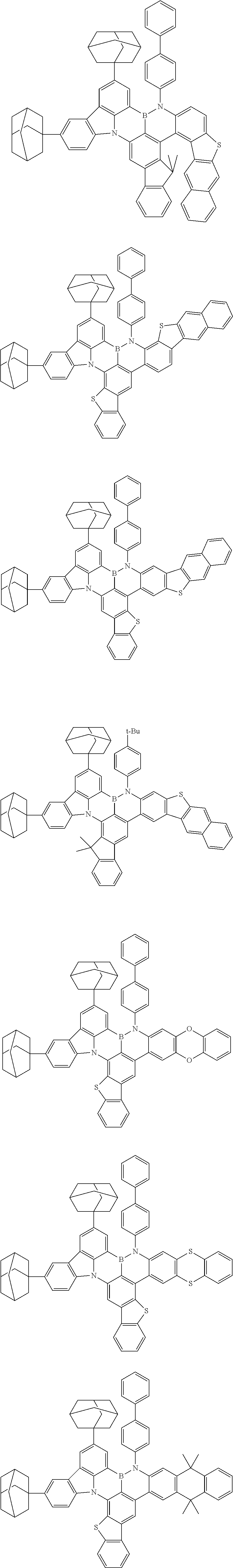 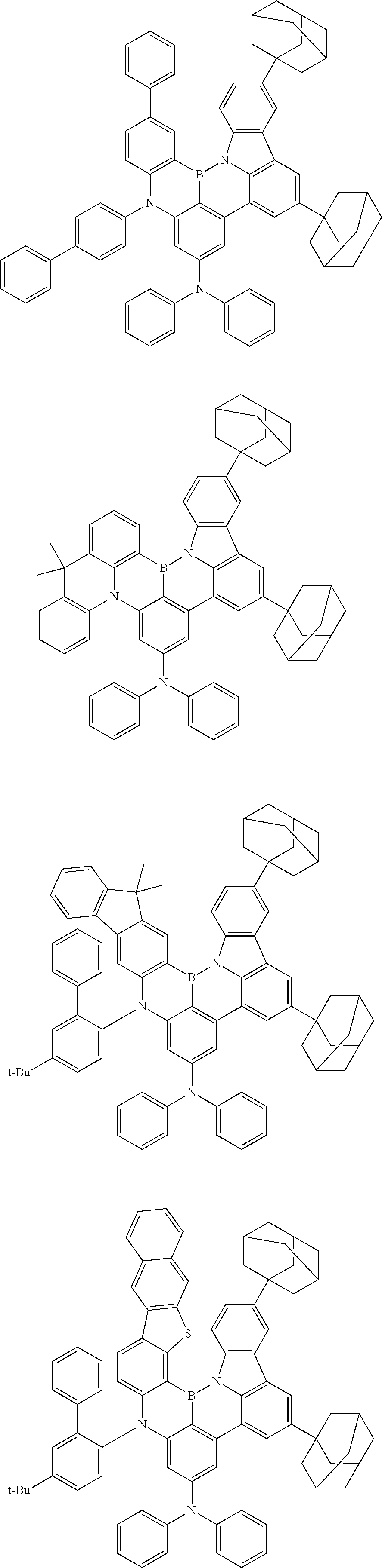 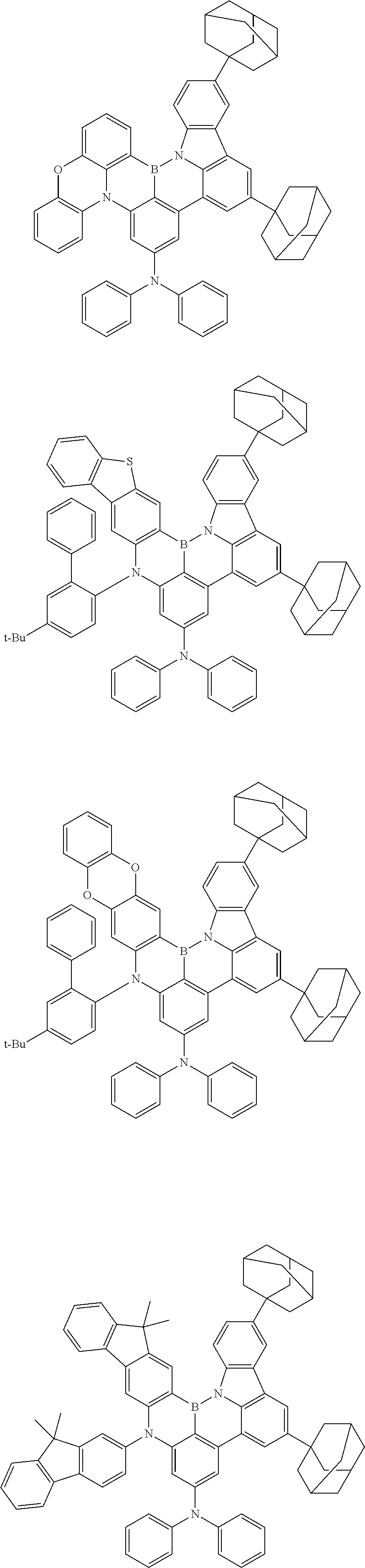 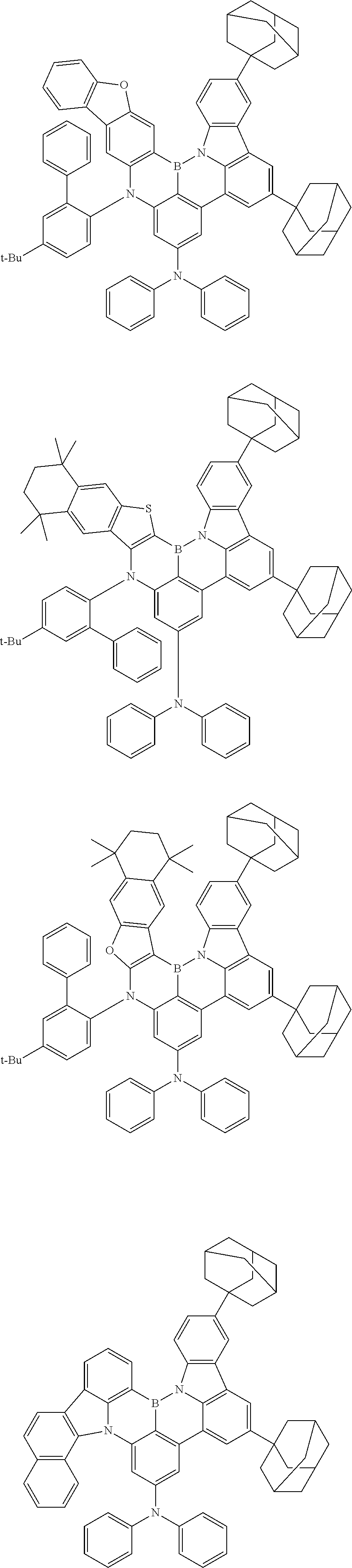 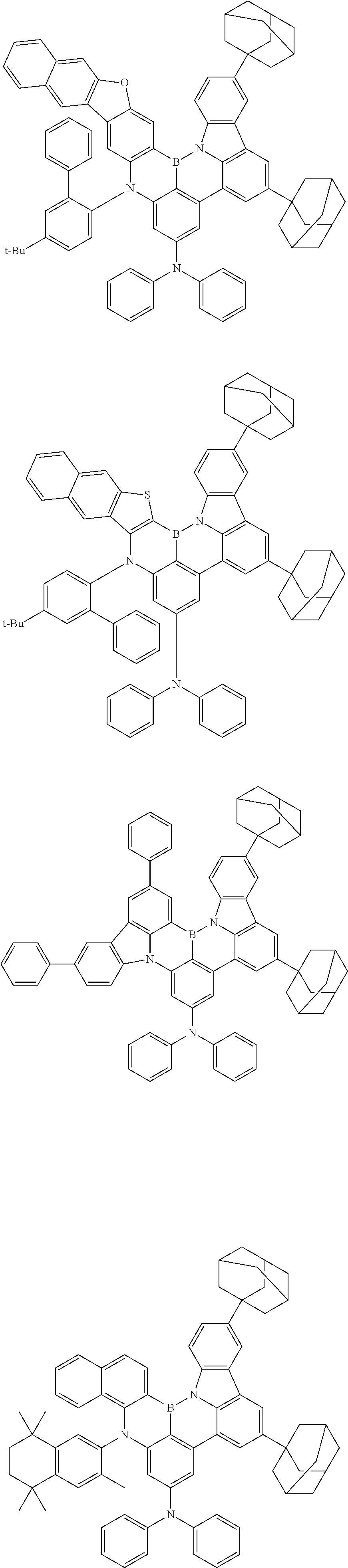 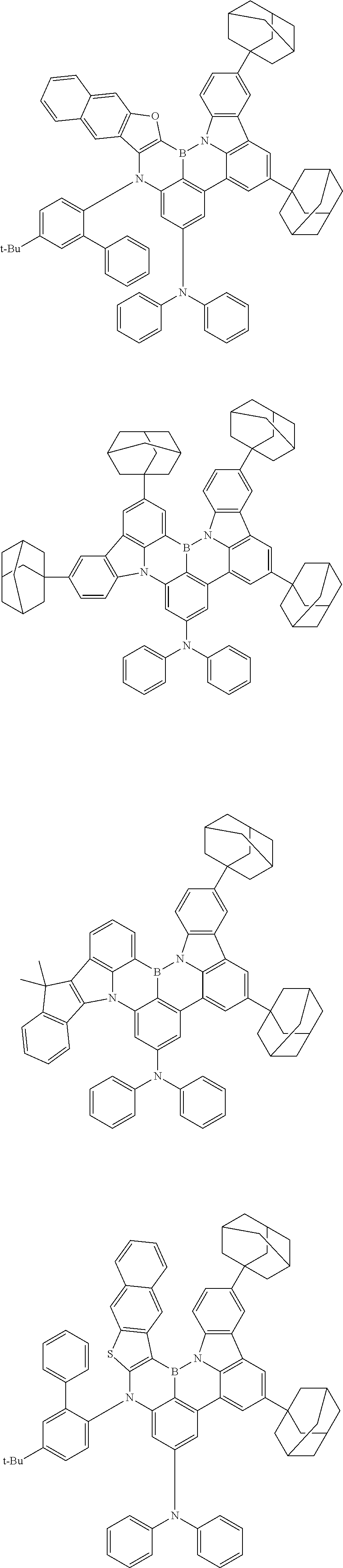 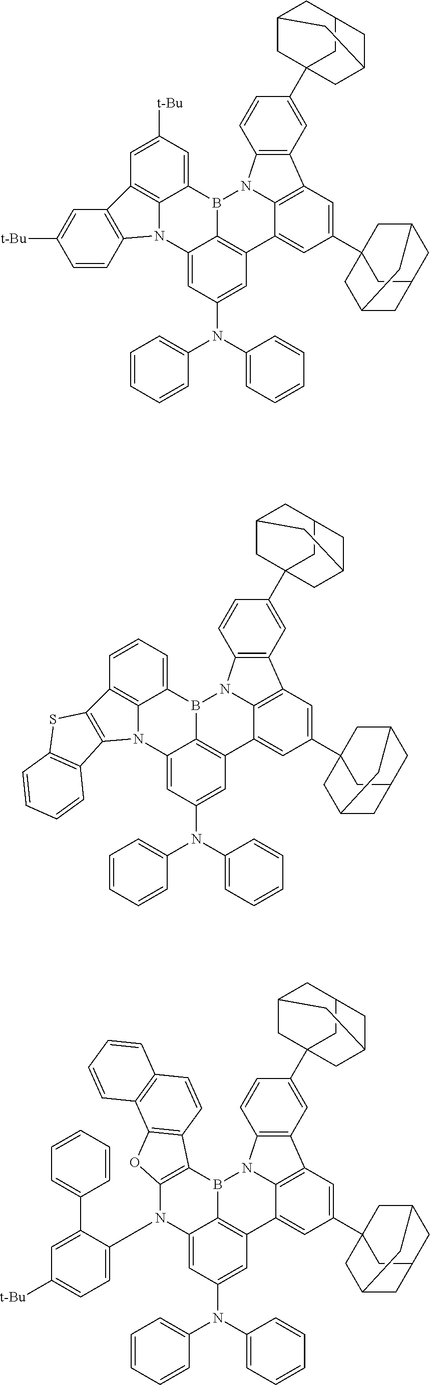 [SMILES: CC(C)(C)c1ccc2c(c1)c1cc(C(C)(C)C)cc3c1n2-c1cc(N(c2ccccc2)c2ccccc2)cc2c1B3n1c3ccc(C45CC6CC(CC(C6)C4)C5)cc3c3cc(C45CC6CC(CC(C6)C4)C5)cc-2c31 ; c1ccc(N(c2ccccc2)c2cc3c4c(c2)-n2c5c(cccc5c5sc6ccccc6c52)B4n2c4ccc(C56CC7CC(CC(C7)C5)C6)cc4c4cc(C56CC7CC(CC(C7)C5)C6)cc-3c42)cc1 ; CC(C)(C)c1ccc(N2c3cc(N(c4ccccc4)c4ccccc4)cc4c3B(c3c2oc2c3ccc3ccccc32)n2c3ccc(C56CC7CC(CC(C7)C5)C6)cc3c3cc(C56CC7CC(CC(C7)C5)C6)cc-4c32)c(-c2ccccc2)c1] 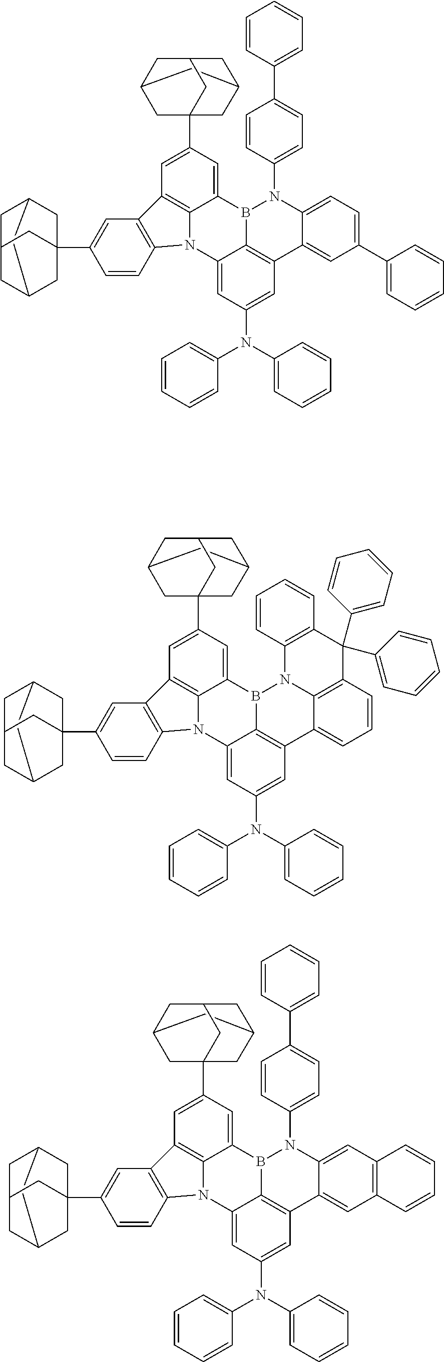 [SMILES: c1ccc(-c2ccc(N3B4c5c(cc(N(c6ccccc6)c6ccccc6)cc5-n5c6ccc(C78CC9CC(CC(C9)C7)C8)cc6c6cc(C78CC9CC(CC(C9)C7)C8)cc4c65)-c4cc(-c5ccccc5)ccc43)cc2)cc1 ; c1ccc(N(c2ccccc2)c2cc3c4c(c2)-n2c5ccc(C67CC8CC(CC(C8)C6)C7)cc5c5cc(C67CC8CC(CC(C8)C6)C7)cc(c52)B4N2c4ccccc4C(c4ccccc4)(c4ccccc4)c4cccc-3c42)cc1 ; c1ccc(-c2ccc(N3B4c5c(cc(N(c6ccccc6)c6ccccc6)cc5-n5c6ccc(C78CC9CC(CC(C9)C7)C8)cc6c6cc(C78CC9CC(CC(C9)C7)C8)cc4c65)-c4cc5ccccc5cc43)cc2)cc1] 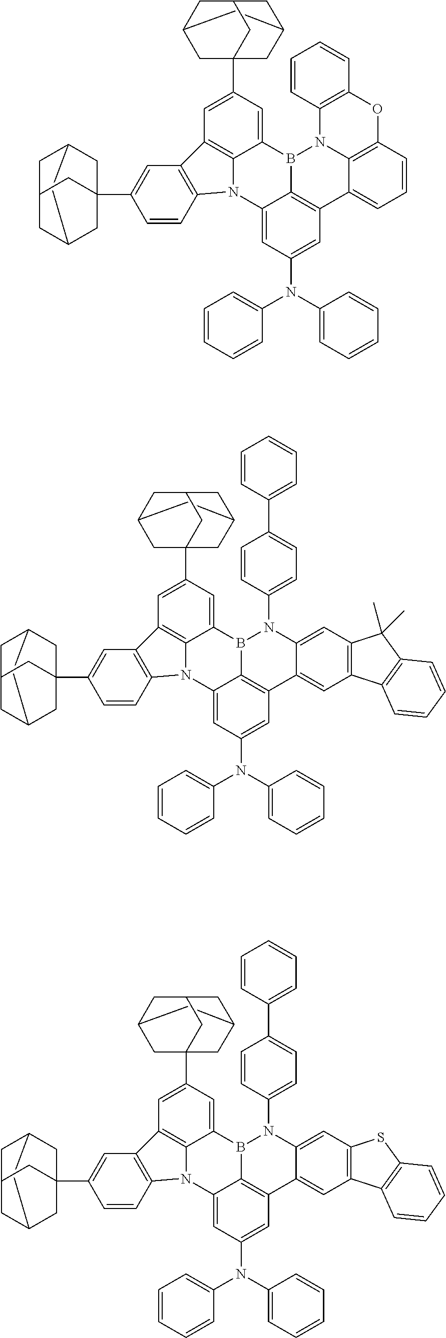 [SMILES: c1ccc(N(c2ccccc2)c2cc3c4c(c2)-n2c5ccc(C67CC8CC(CC(C8)C6)C7)cc5c5cc(C67CC8CC(CC(C8)C6)C7)cc(c52)B4N2c4ccccc4Oc4cccc-3c42)cc1 ; CC1(C)c2ccccc2-c2cc3c(cc21)N(c1ccc(-c2ccccc2)cc1)B1c2c-3cc(N(c3ccccc3)c3ccccc3)cc2-n2c3ccc(C45CC6CC(CC(C6)C4)C5)cc3c3cc(C45CC6CC(CC(C6)C4)C5)cc1c32 ; c1ccc(-c2ccc(N3B4c5c(cc(N(c6ccccc6)c6ccccc6)cc5-n5c6ccc(C78CC9CC(CC(C9)C7)C8)cc6c6cc(C78CC9CC(CC(C9)C7)C8)cc4c65)-c4cc5c(cc43)sc3ccccc35)cc2)cc1] 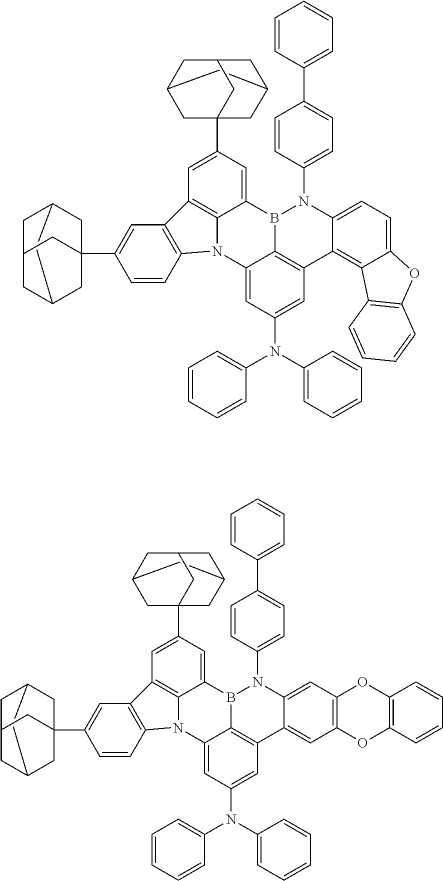 [SMILES: c1ccc(-c2ccc(N3B4c5c(cc(N(c6ccccc6)c6ccccc6)cc5-n5c6ccc(C78CC9CC(CC(C9)C7)C8)cc6c6cc(C78CC9CC(CC(C9)C7)C8)cc4c65)-c4c3ccc3oc5ccccc5c43)cc2)cc1 ; c1ccc(-c2ccc(N3B4c5c(cc(N(c6ccccc6)c6ccccc6)cc5-n5c6ccc(C78CC9CC(CC(C9)C7)C8)cc6c6cc(C78CC9CC(CC(C9)C7)C8)cc4c65)-c4cc5c(cc43)Oc3ccccc3O5)cc2)cc1] 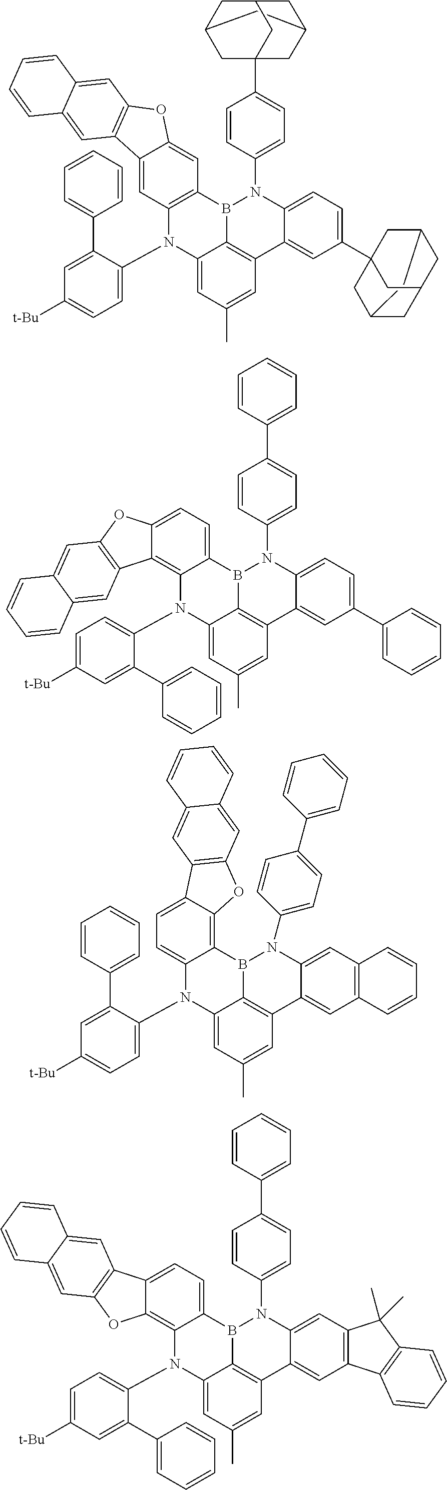 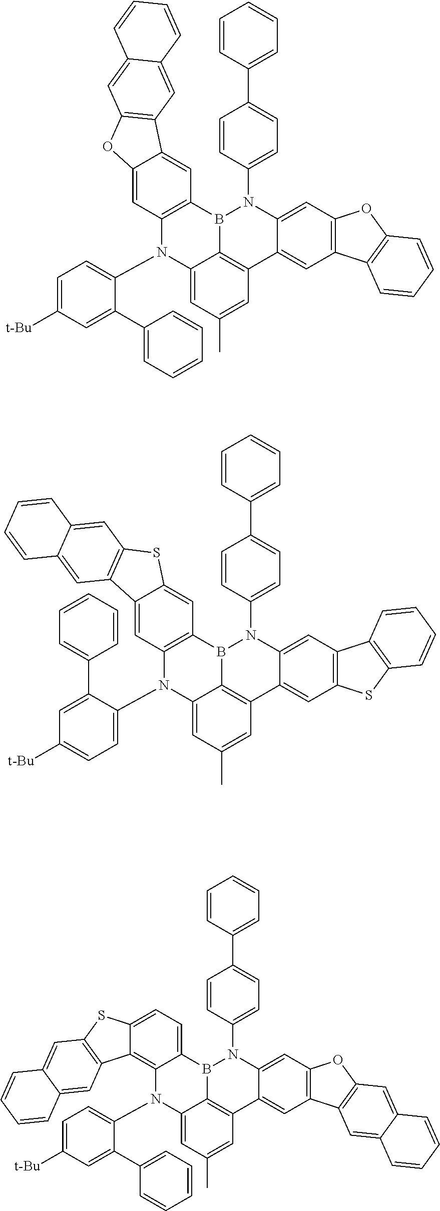 [SMILES: Cc1cc2c3c(c1)N(c1ccc(C(C)(C)C)cc1-c1ccccc1)c1cc4oc5cc6ccccc6cc5c4cc1B3N(c1ccc(-c3ccccc3)cc1)c1cc3oc4ccccc4c3cc1-2 ; Cc1cc2c3c(c1)N(c1ccc(C(C)(C)C)cc1-c1ccccc1)c1cc4c(cc1B3N(c1ccc(-c3ccccc3)cc1)c1cc3c(cc1-2)sc1ccccc13)sc1cc2ccccc2cc14 ; Cc1cc2c3c(c1)N(c1ccc(C(C)(C)C)cc1-c1ccccc1)c1c(ccc4sc5cc6ccccc6cc5c14)B3N(c1ccc(-c3ccccc3)cc1)c1cc3oc4cc5ccccc5cc4c3cc1-2] 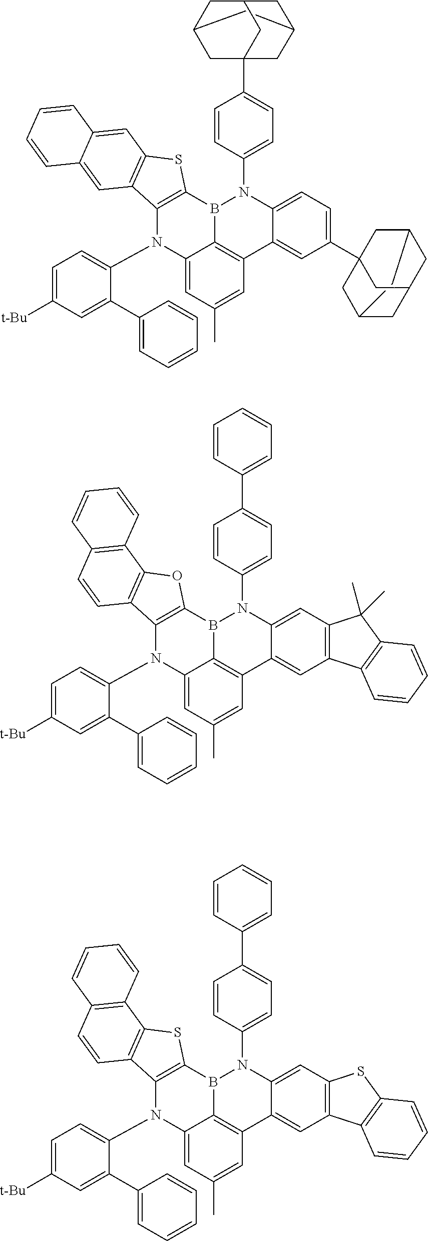 [SMILES: Cc1cc2c3c(c1)N(c1ccc(C(C)(C)C)cc1-c1ccccc1)c1c(sc4cc5ccccc5cc14)B3N(c1ccc(C34CC5CC(CC(C5)C3)C4)cc1)c1ccc(C34CC5CC(CC(C5)C3)C4)cc1-2 ; Cc1cc2c3c(c1)N(c1ccc(C(C)(C)C)cc1-c1ccccc1)c1c(oc4c1ccc1ccccc14)B3N(c1ccc(-c3ccccc3)cc1)c1cc3c(cc1-2)-c1ccccc1C3(C)C ; Cc1cc2c3c(c1)N(c1ccc(C(C)(C)C)cc1-c1ccccc1)c1c(sc4c1ccc1ccccc14)B3N(c1ccc(-c3ccccc3)cc1)c1cc3sc4ccccc4c3cc1-2] 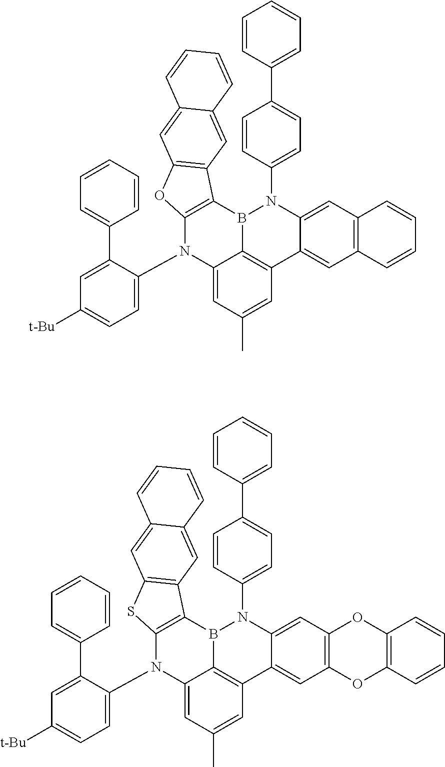 [SMILES: Cc1cc2c3c(c1)N(c1ccc(C(C)(C)C)cc1-c1ccccc1)c1oc4cc5ccccc5cc4c1B3N(c1ccc(-c3ccccc3)cc1)c1cc3ccccc3cc1-2 ; Cc1cc2c3c(c1)N(c1ccc(C(C)(C)C)cc1-c1ccccc1)c1sc4cc5ccccc5cc4c1B3N(c1ccc(-c3ccccc3)cc1)c1cc3c(cc1-2)Oc1ccccc1O3] 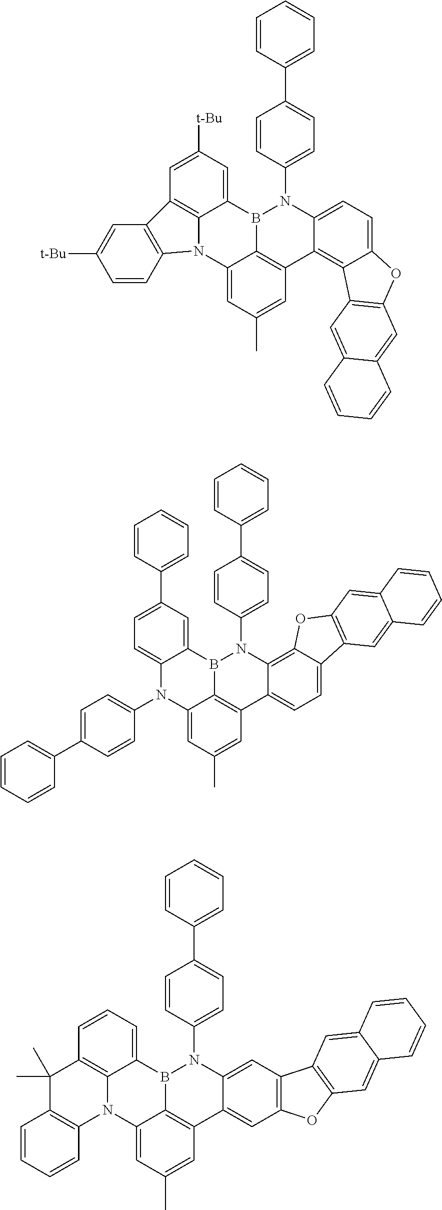 [SMILES: Cc1cc2c3c(c1)-n1c4ccc(C(C)(C)C)cc4c4cc(C(C)(C)C)cc(c41)B3N(c1ccc(-c3ccccc3)cc1)c1ccc3oc4cc5ccccc5cc4c3c1-2 ; Cc1cc2c3c(c1)N(c1ccc(-c4ccccc4)cc1)c1ccc(-c4ccccc4)cc1B3N(c1ccc(-c3ccccc3)cc1)c1c-2ccc2c1oc1cc3ccccc3cc12 ; Cc1cc2c3c(c1)N1c4ccccc4C(C)(C)c4cccc(c41)B3N(c1ccc(-c3ccccc3)cc1)c1cc3c(cc1-2)oc1cc2ccccc2cc13] 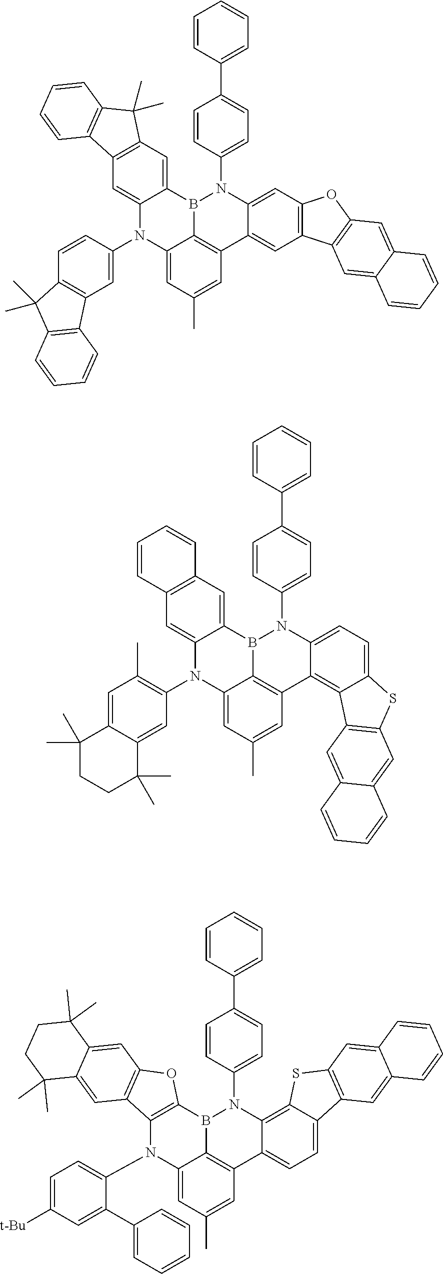 [SMILES: Cc1cc2c3c(c1)N(c1ccc4c(c1)-c1ccccc1C4(C)C)c1cc4c(cc1B3N(c1ccc(-c3ccccc3)cc1)c1cc3oc5cc6ccccc6cc5c3cc1-2)C(C)(C)c1ccccc1-4 ; Cc1cc2c3c(c1)N(c1cc4c(cc1C)C(C)(C)CCC4(C)C)c1cc4ccccc4cc1B3N(c1ccc(-c3ccccc3)cc1)c1ccc3sc4cc5ccccc5cc4c3c1-2 ; Cc1cc2c3c(c1)N(c1ccc(C(C)(C)C)cc1-c1ccccc1)c1c(oc4cc5c(cc14)C(C)(C)CCC5(C)C)B3N(c1ccc(-c3ccccc3)cc1)c1c-2ccc2c1sc1cc3ccccc3cc12] 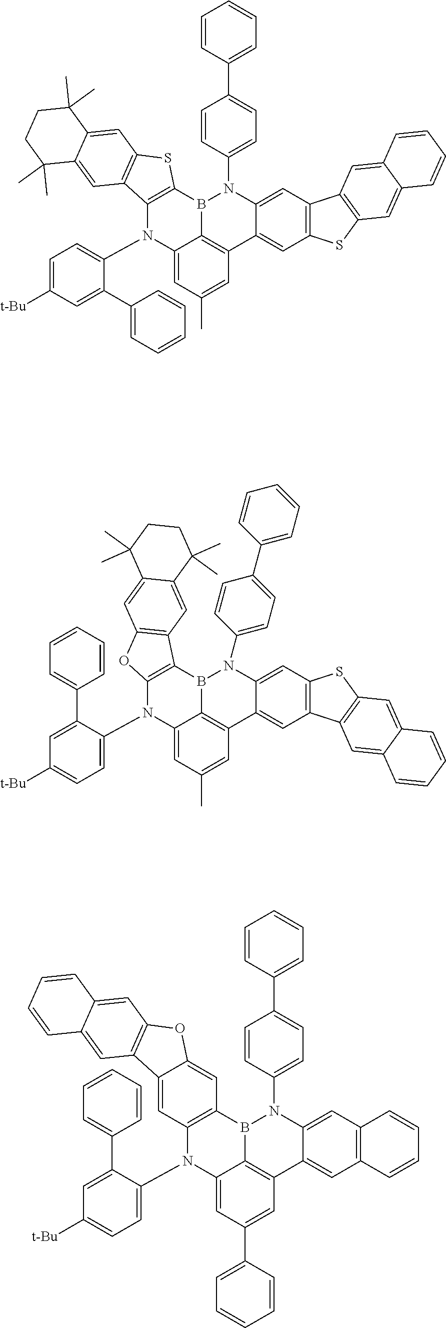 [SMILES: Cc1cc2c3c(c1)N(c1ccc(C(C)(C)C)cc1-c1ccccc1)c1c(sc4cc5c(cc14)C(C)(C)CCC5(C)C)B3N(c1ccc(-c3ccccc3)cc1)c1cc3c(cc1-2)sc1cc2ccccc2cc13 ; Cc1cc2c3c(c1)N(c1ccc(C(C)(C)C)cc1-c1ccccc1)c1oc4cc5c(cc4c1B3N(c1ccc(-c3ccccc3)cc1)c1cc3sc4cc6ccccc6cc4c3cc1-2)C(C)(C)CCC5(C)C ; CC(C)(C)c1ccc(N2c3cc4c(cc3B3c5c(cc(-c6ccccc6)cc52)-c2cc5ccccc5cc2N3c2ccc(-c3ccccc3)cc2)oc2cc3ccccc3cc24)c(-c2ccccc2)c1] 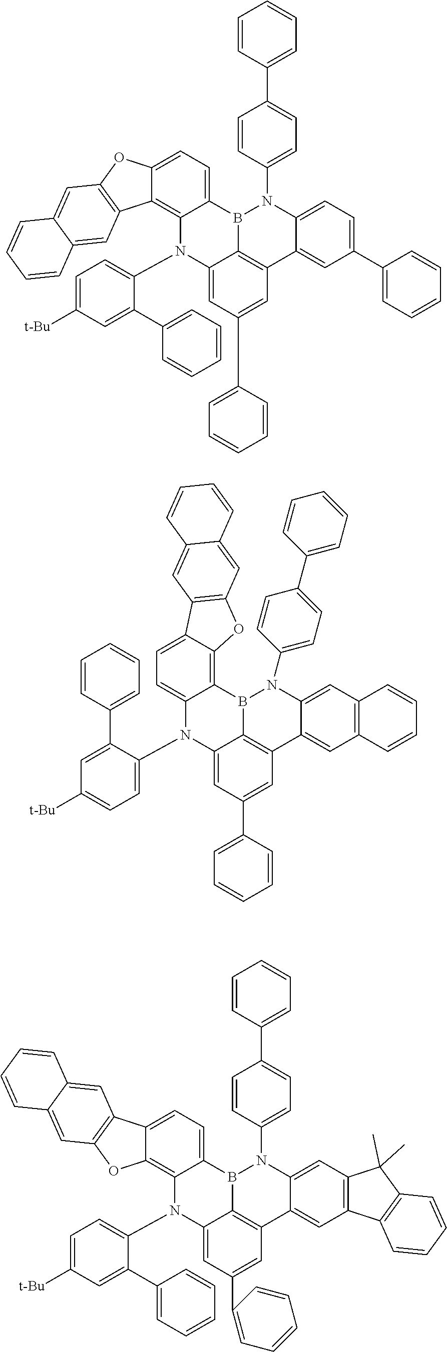 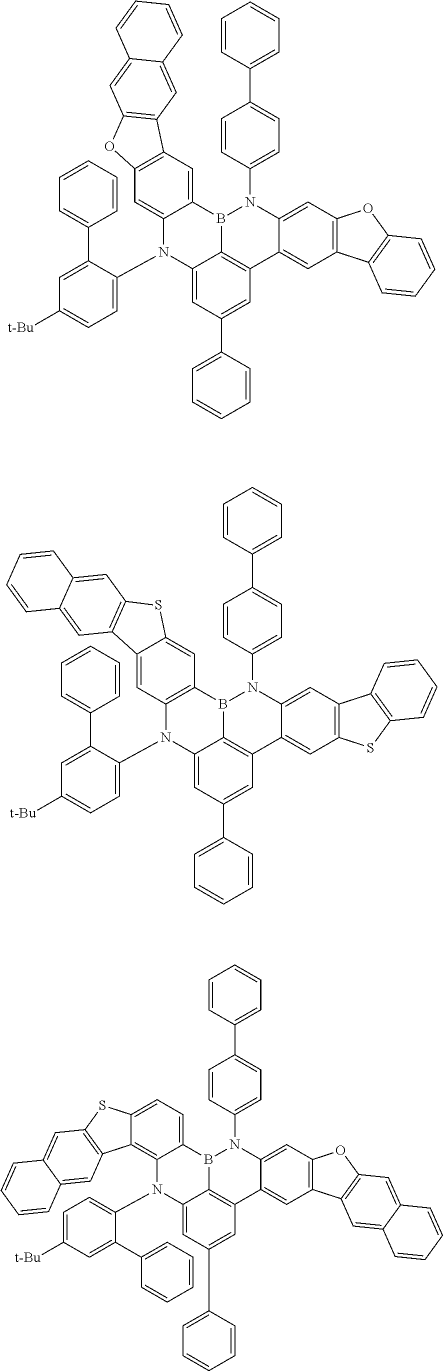 [SMILES: CC(C)(C)c1ccc(N2c3cc4oc5cc6ccccc6cc5c4cc3B3c4c(cc(-c5ccccc5)cc42)-c2cc4c(cc2N3c2ccc(-c3ccccc3)cc2)oc2ccccc24)c(-c2ccccc2)c1 ; CC(C)(C)c1ccc(N2c3cc4c(cc3B3c5c(cc(-c6ccccc6)cc52)-c2cc5sc6ccccc6c5cc2N3c2ccc(-c3ccccc3)cc2)sc2cc3ccccc3cc24)c(-c2ccccc2)c1 ; CC(C)(C)c1ccc(N2c3cc(-c4ccccc4)cc4c3B(c3ccc5sc6cc7ccccc7cc6c5c32)N(c2ccc(-c3ccccc3)cc2)c2cc3oc5cc6ccccc6cc5c3cc2-4)c(-c2ccccc2)c1] 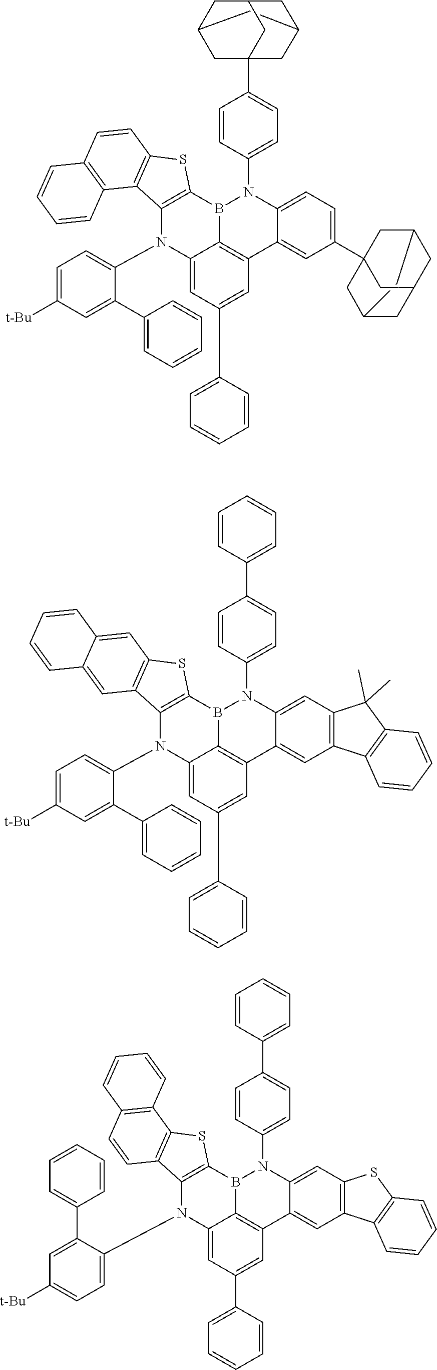 [SMILES: CC(C)(C)c1ccc(N2c3cc(-c4ccccc4)cc4c3B(c3sc5ccc6ccccc6c5c32)N(c2ccc(C35CC6CC(CC(C6)C3)C5)cc2)c2ccc(C35CC6CC(CC(C6)C3)C5)cc2-4)c(-c2ccccc2)c1 ; CC(C)(C)c1ccc(N2c3cc(-c4ccccc4)cc4c3B(c3sc5cc6ccccc6cc5c32)N(c2ccc(-c3ccccc3)cc2)c2cc3c(cc2-4)-c2ccccc2C3(C)C)c(-c2ccccc2)c1 ; CC(C)(C)c1ccc(N2c3cc(-c4ccccc4)cc4c3B(c3sc5c(ccc6ccccc65)c32)N(c2ccc(-c3ccccc3)cc2)c2cc3sc5ccccc5c3cc2-4)c(-c2ccccc2)c1] 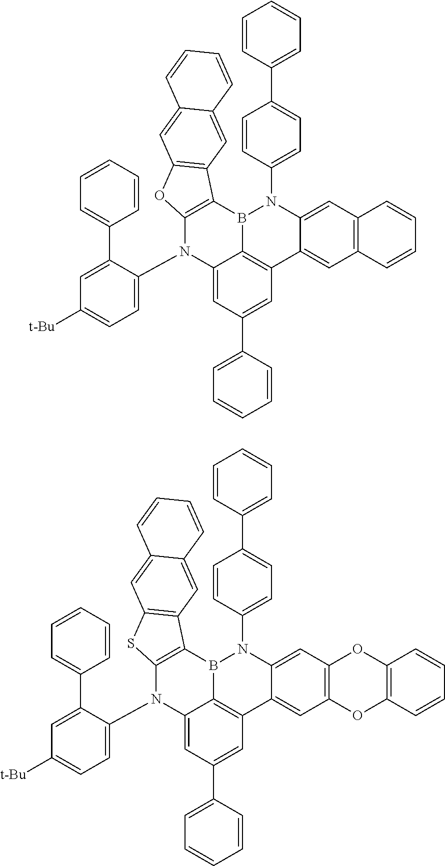 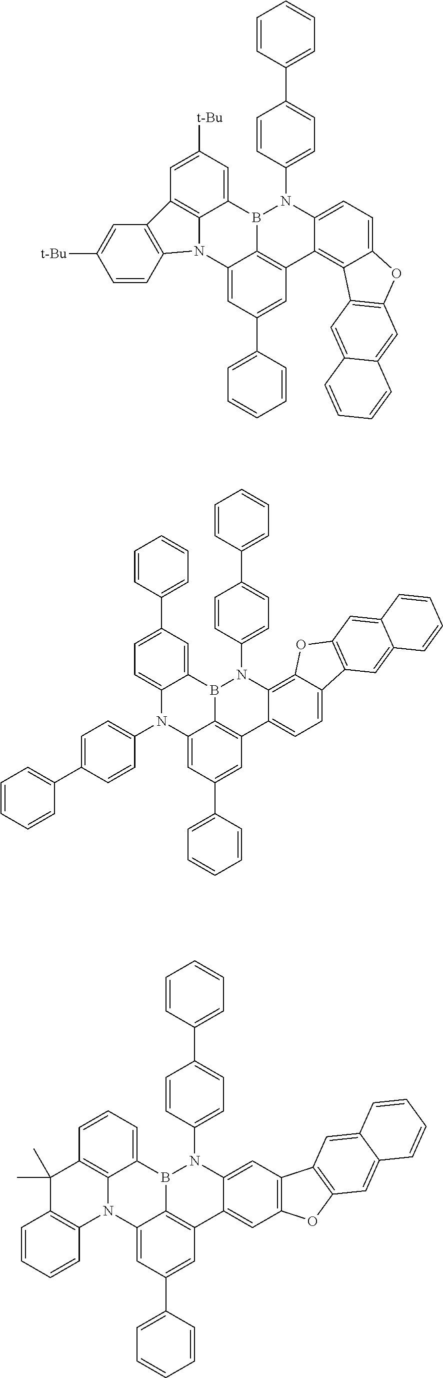 [SMILES: CC(C)(C)c1ccc2c(c1)c1cc(C(C)(C)C)cc3c1n2-c1cc(-c2ccccc2)cc2c1B3N(c1ccc(-c3ccccc3)cc1)c1ccc3oc4cc5ccccc5cc4c3c1-2 ; c1ccc(-c2ccc(N3B4c5cc(-c6ccccc6)ccc5N(c5ccc(-c6ccccc6)cc5)c5cc(-c6ccccc6)cc(c54)-c4ccc5c(oc6cc7ccccc7cc65)c43)cc2)cc1 ; CC1(C)c2ccccc2N2c3cc(-c4ccccc4)cc4c3B(c3cccc1c32)N(c1ccc(-c2ccccc2)cc1)c1cc2c(cc1-4)oc1cc3ccccc3cc12] 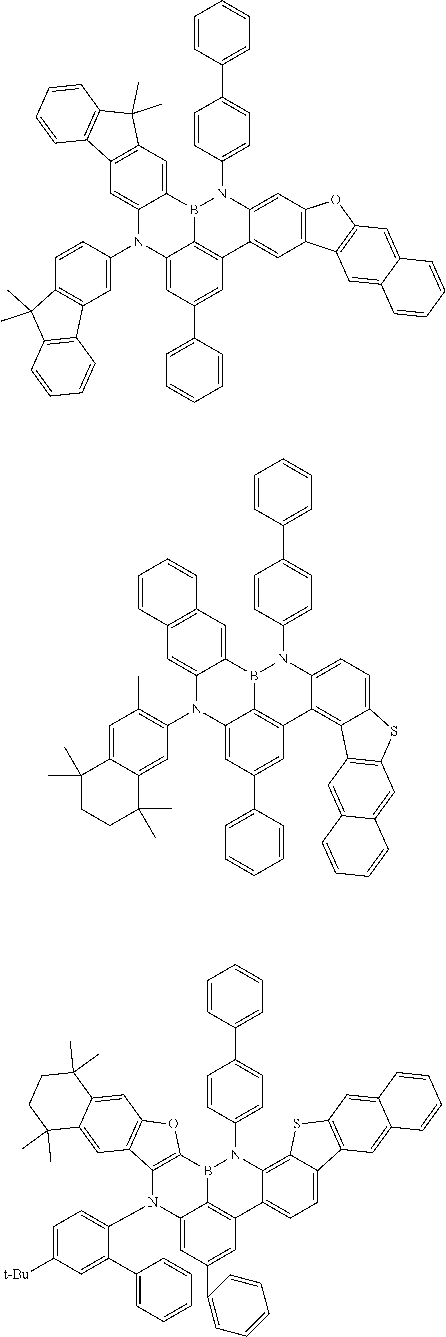 [SMILES: CC1(C)c2ccccc2-c2cc(N3c4cc5c(cc4B4c6c(cc(-c7ccccc7)cc63)-c3cc6c(cc3N4c3ccc(-c4ccccc4)cc3)oc3cc4ccccc4cc36)C(C)(C)c3ccccc3-5)ccc21 ; Cc1cc2c(cc1N1c3cc4ccccc4cc3B3c4c(cc(-c5ccccc5)cc41)-c1c(ccc4sc5cc6ccccc6cc5c14)N3c1ccc(-c3ccccc3)cc1)C(C)(C)CCC2(C)C ; CC(C)(C)c1ccc(N2c3cc(-c4ccccc4)cc4c3B(c3oc5cc6c(cc5c32)C(C)(C)CCC6(C)C)N(c2ccc(-c3ccccc3)cc2)c2c-4ccc3c2sc2cc4ccccc4cc23)c(-c2ccccc2)c1] 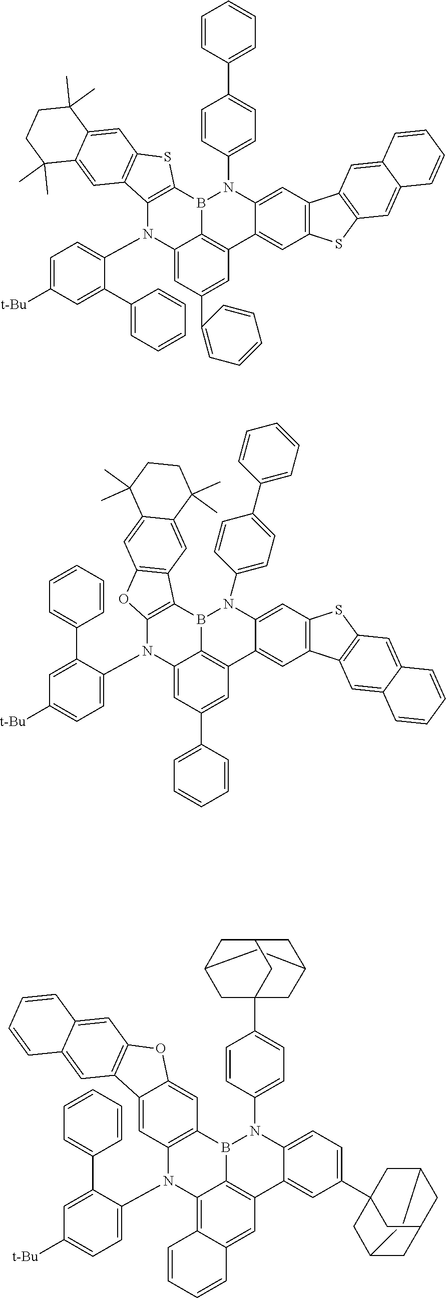 [SMILES: CC(C)(C)c1ccc(N2c3cc(-c4ccccc4)cc4c3B(c3sc5cc6c(cc5c32)C(C)(C)CCC6(C)C)N(c2ccc(-c3ccccc3)cc2)c2cc3c(cc2-4)sc2cc4ccccc4cc23)c(-c2ccccc2)c1 ; CC(C)(C)c1ccc(N2c3cc(-c4ccccc4)cc4c3B(c3c2oc2cc5c(cc32)C(C)(C)CCC5(C)C)N(c2ccc(-c3ccccc3)cc2)c2cc3sc5cc6ccccc6cc5c3cc2-4)c(-c2ccccc2)c1 ; CC(C)(C)c1ccc(N2c3cc4c(cc3B3c5c(cc6ccccc6c52)-c2cc(C56CC7CC(CC(C7)C5)C6)ccc2N3c2ccc(C35CC6CC(CC(C6)C3)C5)cc2)oc2cc3ccccc3cc24)c(-c2ccccc2)c1] 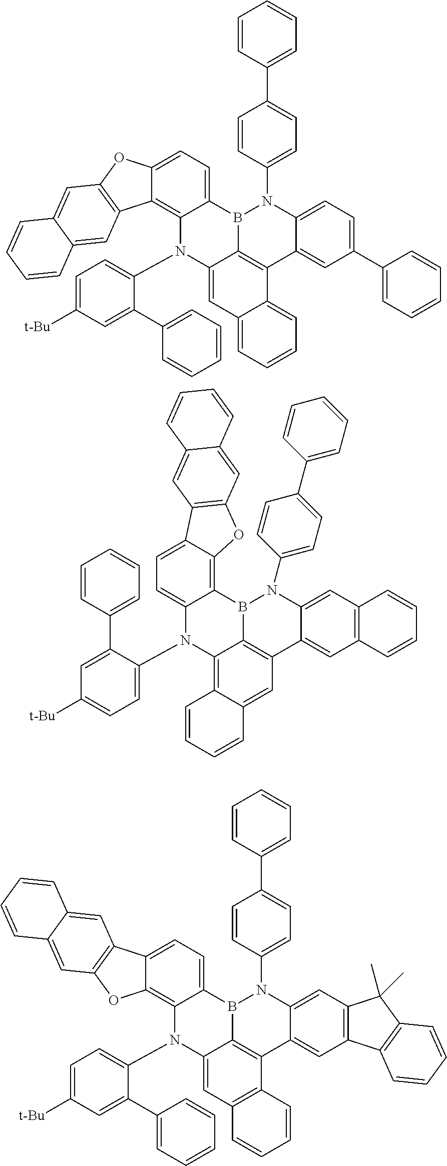 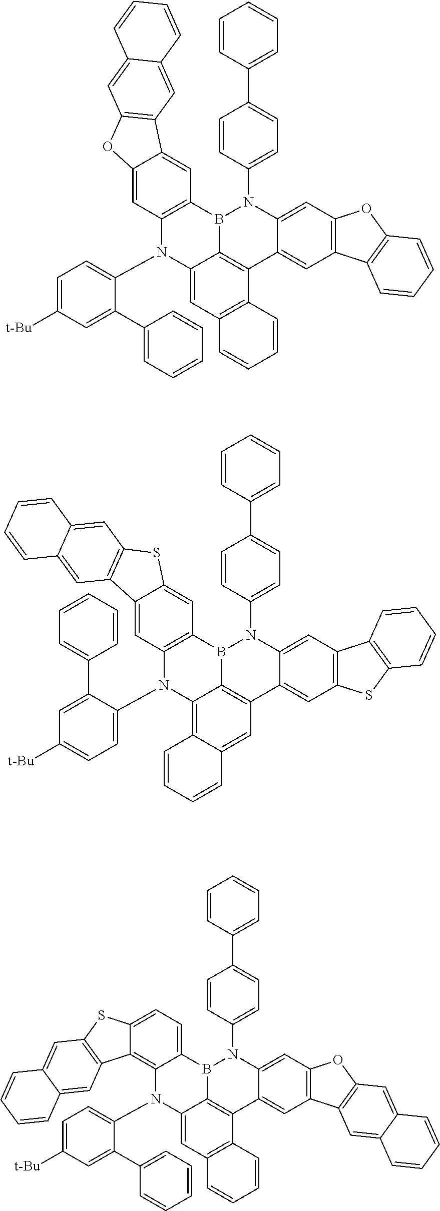 [SMILES: CC(C)(C)c1ccc(N2c3cc4oc5cc6ccccc6cc5c4cc3B3c4c2cc2ccccc2c4-c2cc4c(cc2N3c2ccc(-c3ccccc3)cc2)oc2ccccc24)c(-c2ccccc2)c1 ; CC(C)(C)c1ccc(N2c3cc4c(cc3B3c5c(cc6ccccc6c52)-c2cc5sc6ccccc6c5cc2N3c2ccc(-c3ccccc3)cc2)sc2cc3ccccc3cc24)c(-c2ccccc2)c1 ; CC(C)(C)c1ccc(N2c3cc4ccccc4c4c3B(c3ccc5sc6cc7ccccc7cc6c5c32)N(c2ccc(-c3ccccc3)cc2)c2cc3oc5cc6ccccc6cc5c3cc2-4)c(-c2ccccc2)c1] 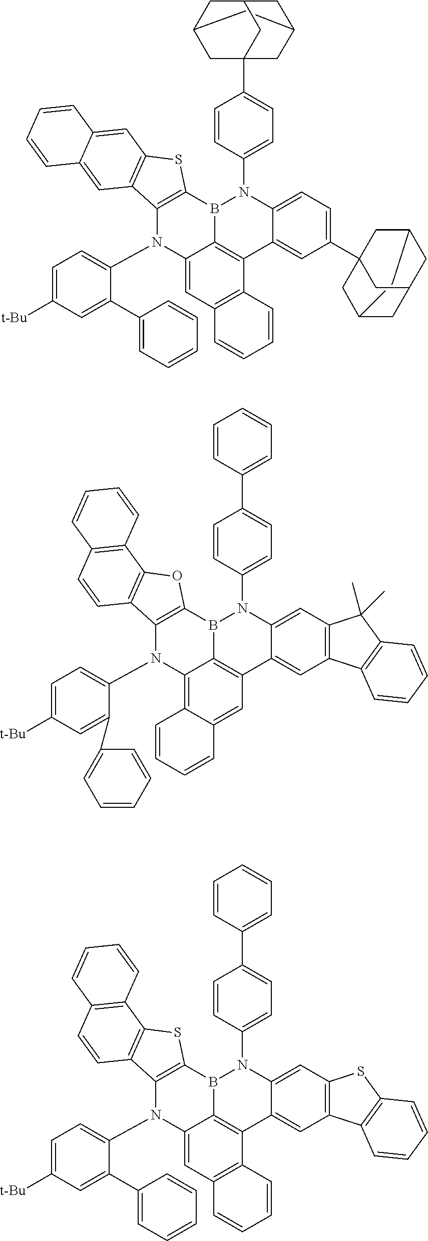 [SMILES: CC(C)(C)c1ccc(N2c3cc4ccccc4c4c3B(c3sc5cc6ccccc6cc5c32)N(c2ccc(C35CC6CC(CC(C6)C3)C5)cc2)c2ccc(C35CC6CC(CC(C6)C3)C5)cc2-4)c(-c2ccccc2)c1 ; CC(C)(C)c1ccc(N2c3c4c(cc5ccccc35)-c3cc5c(cc3N(c3ccc(-c6ccccc6)cc3)B4c3oc4c(ccc6ccccc64)c32)C(C)(C)c2ccccc2-5)c(-c2ccccc2)c1 ; CC(C)(C)c1ccc(N2c3cc4ccccc4c4c3B(c3sc5c(ccc6ccccc65)c32)N(c2ccc(-c3ccccc3)cc2)c2cc3sc5ccccc5c3cc2-4)c(-c2ccccc2)c1] 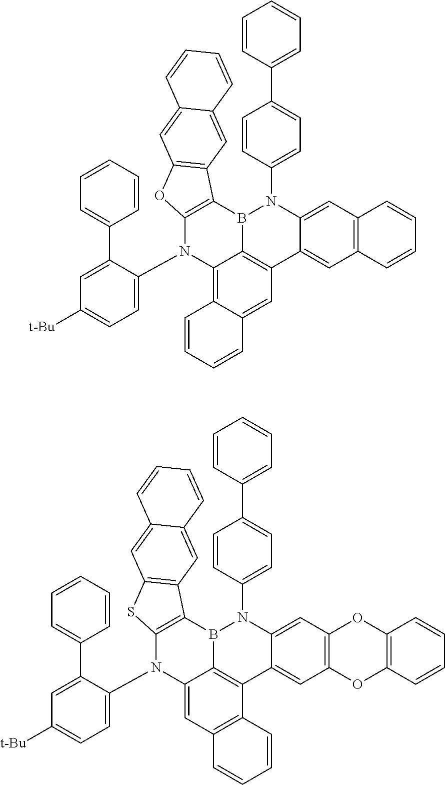 [SMILES: CC(C)(C)c1ccc(N2c3oc4cc5ccccc5cc4c3B3c4c(cc5ccccc5c42)-c2cc4ccccc4cc2N3c2ccc(-c3ccccc3)cc2)c(-c2ccccc2)c1 ; CC(C)(C)c1ccc(N2c3cc4ccccc4c4c3B(c3c2sc2cc5ccccc5cc32)N(c2ccc(-c3ccccc3)cc2)c2cc3c(cc2-4)Oc2ccccc2O3)c(-c2ccccc2)c1] 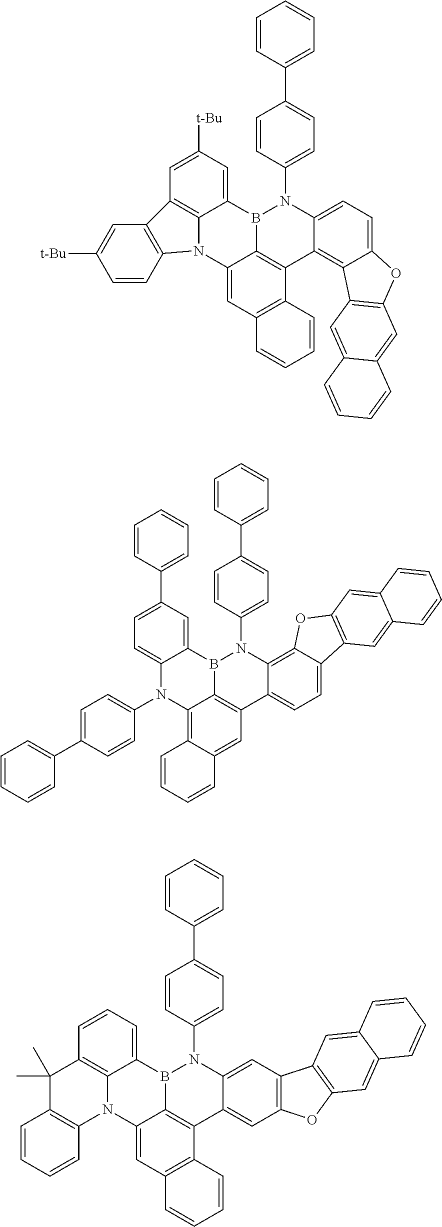 [SMILES: CC(C)(C)c1ccc2c(c1)c1cc(C(C)(C)C)cc3c1n2-c1cc2ccccc2c2c1B3N(c1ccc(-c3ccccc3)cc1)c1ccc3oc4cc5ccccc5cc4c3c1-2 ; c1ccc(-c2ccc(N3B4c5cc(-c6ccccc6)ccc5N(c5ccc(-c6ccccc6)cc5)c5c4c(cc4ccccc54)-c4ccc5c(oc6cc7ccccc7cc65)c43)cc2)cc1 ; CC1(C)c2ccccc2N2c3cc4ccccc4c4c3B(c3cccc1c32)N(c1ccc(-c2ccccc2)cc1)c1cc2c(cc1-4)oc1cc3ccccc3cc12] 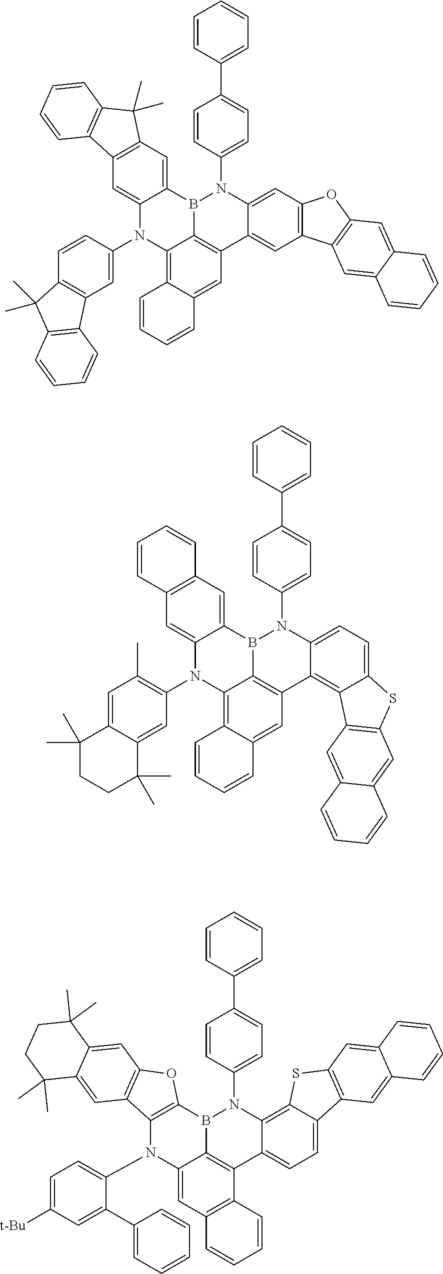 [SMILES: CC1(C)c2ccccc2-c2cc(N3c4cc5c(cc4B4c6c(cc7ccccc7c63)-c3cc6c(cc3N4c3ccc(-c4ccccc4)cc3)oc3cc4ccccc4cc36)C(C)(C)c3ccccc3-5)ccc21 ; Cc1cc2c(cc1N1c3cc4ccccc4cc3B3c4c(cc5ccccc5c41)-c1c(ccc4sc5cc6ccccc6cc5c14)N3c1ccc(-c3ccccc3)cc1)C(C)(C)CCC2(C)C ; CC(C)(C)c1ccc(N2c3cc4ccccc4c4c3B(c3oc5cc6c(cc5c32)C(C)(C)CCC6(C)C)N(c2ccc(-c3ccccc3)cc2)c2c-4ccc3c2sc2cc4ccccc4cc23)c(-c2ccccc2)c1] 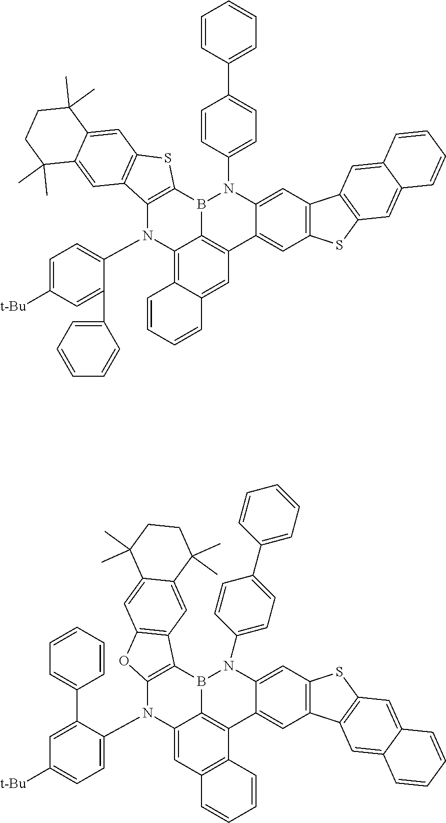 [SMILES: CC(C)(C)c1ccc(N2c3c4c(cc5ccccc35)-c3cc5sc6cc7ccccc7cc6c5cc3N(c3ccc(-c5ccccc5)cc3)B4c3sc4cc5c(cc4c32)C(C)(C)CCC5(C)C)c(-c2ccccc2)c1 ; CC(C)(C)c1ccc(N2c3cc4ccccc4c4c3B(c3c2oc2cc5c(cc32)C(C)(C)CCC5(C)C)N(c2ccc(-c3ccccc3)cc2)c2cc3sc5cc6ccccc6cc5c3cc2-4)c(-c2ccccc2)c1] 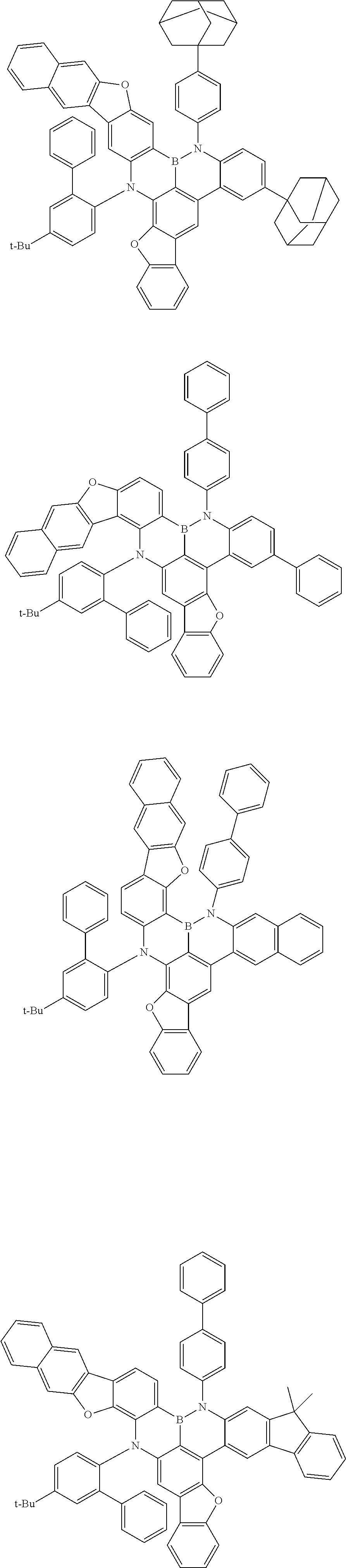 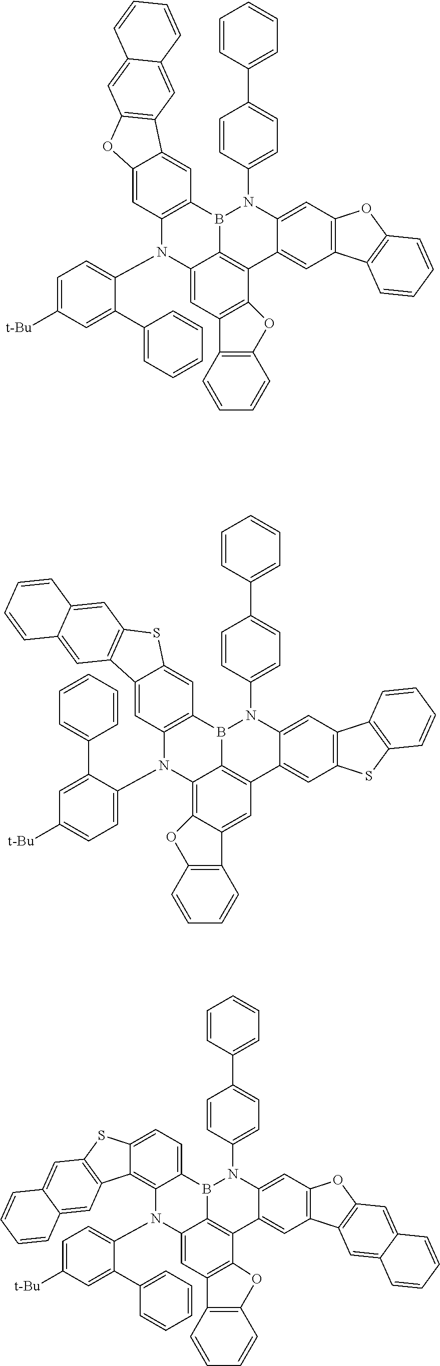 [SMILES: CC(C)(C)c1ccc(N2c3cc4oc5cc6ccccc6cc5c4cc3B3c4c2cc2c(oc5ccccc52)c4-c2cc4c(cc2N3c2ccc(-c3ccccc3)cc2)oc2ccccc24)c(-c2ccccc2)c1 ; CC(C)(C)c1ccc(N2c3cc4c(cc3B3c5c(cc6c(oc7ccccc76)c52)-c2cc5sc6ccccc6c5cc2N3c2ccc(-c3ccccc3)cc2)sc2cc3ccccc3cc24)c(-c2ccccc2)c1 ; CC(C)(C)c1ccc(N2c3cc4c(oc5ccccc54)c4c3B(c3ccc5sc6cc7ccccc7cc6c5c32)N(c2ccc(-c3ccccc3)cc2)c2cc3oc5cc6ccccc6cc5c3cc2-4)c(-c2ccccc2)c1] 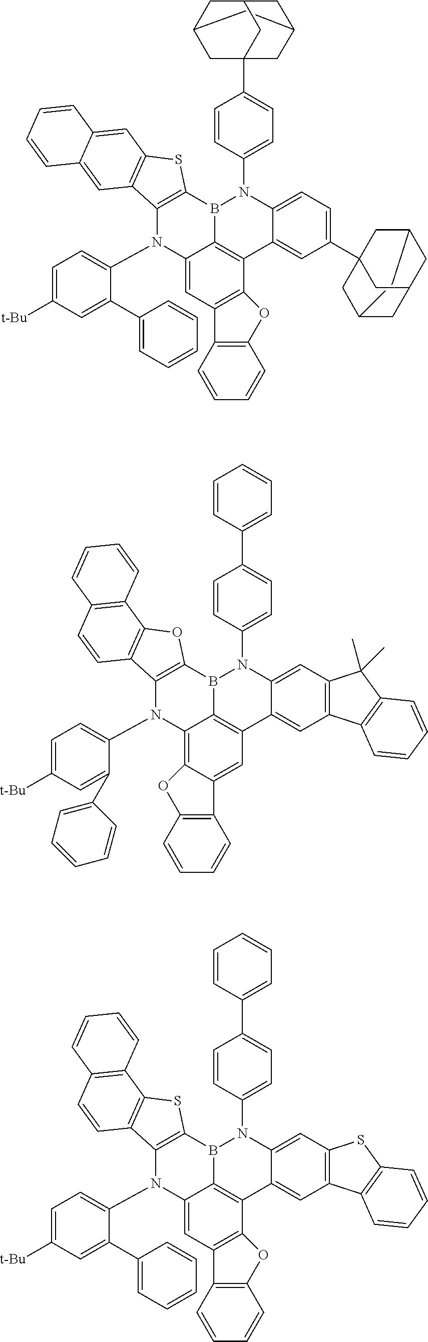 [SMILES: CC(C)(C)c1ccc(N2c3cc4c(oc5ccccc54)c4c3B(c3sc5cc6ccccc6cc5c32)N(c2ccc(C35CC6CC(CC(C6)C3)C5)cc2)c2ccc(C35CC6CC(CC(C6)C3)C5)cc2-4)c(-c2ccccc2)c1 ; CC(C)(C)c1ccc(N2c3c(oc4c3ccc3ccccc34)B3c4c(cc5c(oc6ccccc65)c42)-c2cc4c(cc2N3c2ccc(-c3ccccc3)cc2)C(C)(C)c2ccccc2-4)c(-c2ccccc2)c1 ; CC(C)(C)c1ccc(N2c3cc4c(oc5ccccc54)c4c3B(c3sc5c(ccc6ccccc65)c32)N(c2ccc(-c3ccccc3)cc2)c2cc3sc5ccccc5c3cc2-4)c(-c2ccccc2)c1] 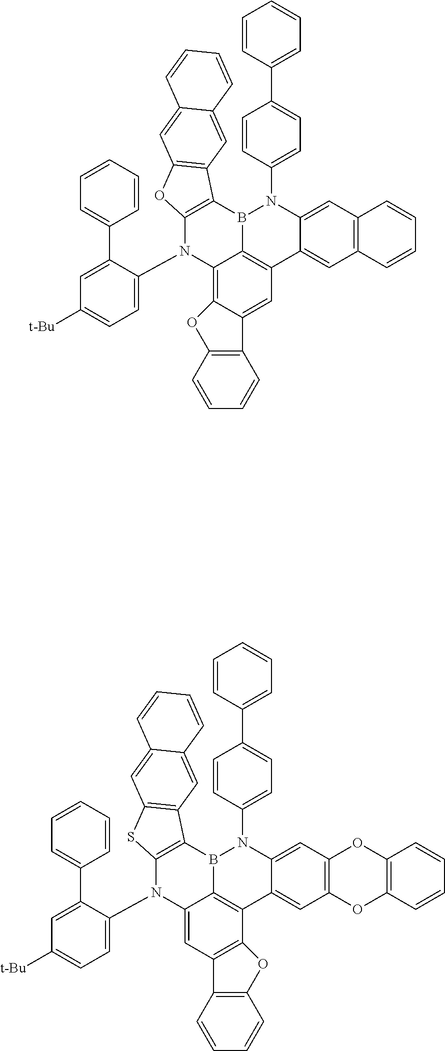 [SMILES: CC(C)(C)c1ccc(N2c3oc4cc5ccccc5cc4c3B3c4c(cc5c(oc6ccccc65)c42)-c2cc4ccccc4cc2N3c2ccc(-c3ccccc3)cc2)c(-c2ccccc2)c1 ; CC(C)(C)c1ccc(N2c3cc4c(oc5ccccc54)c4c3B(c3c2sc2cc5ccccc5cc32)N(c2ccc(-c3ccccc3)cc2)c2cc3c(cc2-4)Oc2ccccc2O3)c(-c2ccccc2)c1] 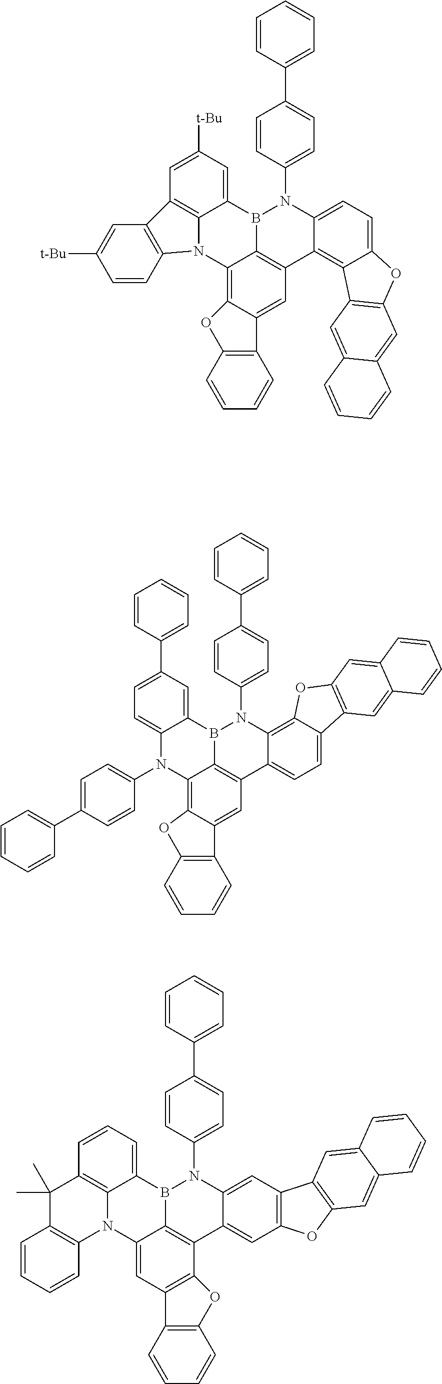 [SMILES: CC(C)(C)c1ccc2c(c1)c1cc(C(C)(C)C)cc3c1n2-c1c2c(cc4c1oc1ccccc14)-c1c(ccc4oc5cc6ccccc6cc5c14)N(c1ccc(-c4ccccc4)cc1)B23 ; c1ccc(-c2ccc(N3B4c5cc(-c6ccccc6)ccc5N(c5ccc(-c6ccccc6)cc5)c5c4c(cc4c5oc5ccccc54)-c4ccc5c(oc6cc7ccccc7cc65)c43)cc2)cc1 ; CC1(C)c2ccccc2N2c3cc4c(oc5ccccc54)c4c3B(c3cccc1c32)N(c1ccc(-c2ccccc2)cc1)c1cc2c(cc1-4)oc1cc3ccccc3cc12] 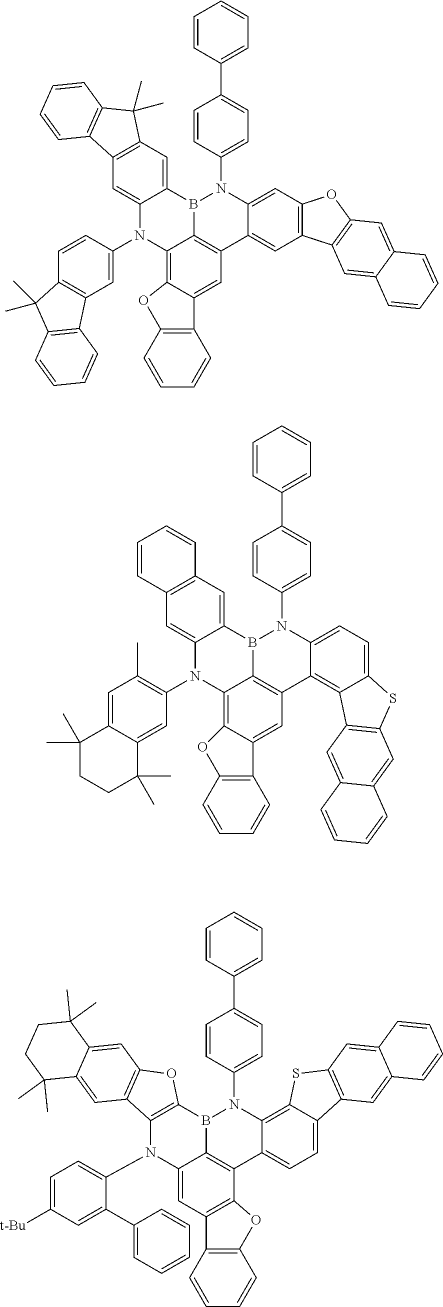 [SMILES: CC1(C)c2ccccc2-c2cc(N3c4cc5c(cc4B4c6c(cc7c(oc8ccccc87)c63)-c3cc6c(cc3N4c3ccc(-c4ccccc4)cc3)oc3cc4ccccc4cc36)C(C)(C)c3ccccc3-5)ccc21 ; Cc1cc2c(cc1N1c3cc4ccccc4cc3B3c4c(cc5c(oc6ccccc65)c41)-c1c(ccc4sc5cc6ccccc6cc5c14)N3c1ccc(-c3ccccc3)cc1)C(C)(C)CCC2(C)C ; CC(C)(C)c1ccc(N2c3cc4c(oc5ccccc54)c4c3B(c3oc5cc6c(cc5c32)C(C)(C)CCC6(C)C)N(c2ccc(-c3ccccc3)cc2)c2c-4ccc3c2sc2cc4ccccc4cc23)c(-c2ccccc2)c1] 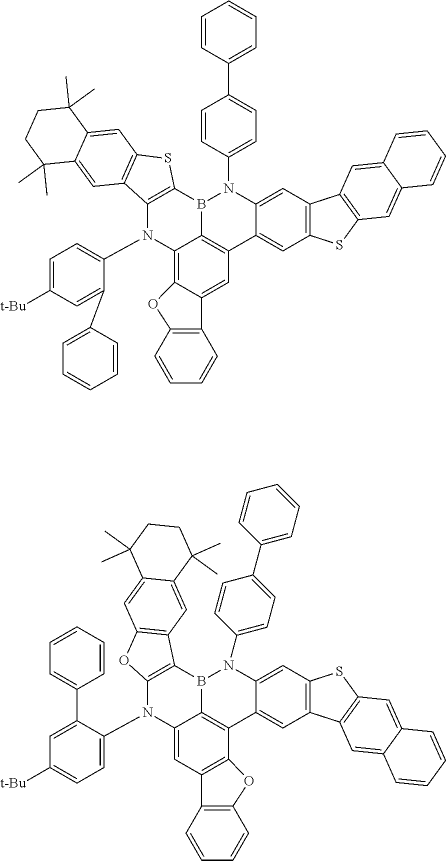 [SMILES: CC(C)(C)c1ccc(N2c3c(sc4cc5c(cc34)C(C)(C)CCC5(C)C)B3c4c(cc5c(oc6ccccc65)c42)-c2cc4sc5cc6ccccc6cc5c4cc2N3c2ccc(-c3ccccc3)cc2)c(-c2ccccc2)c1 ; CC(C)(C)c1ccc(N2c3cc4c(oc5ccccc54)c4c3B(c3c2oc2cc5c(cc32)C(C)(C)CCC5(C)C)N(c2ccc(-c3ccccc3)cc2)c2cc3sc5cc6ccccc6cc5c3cc2-4)c(-c2ccccc2)c1] 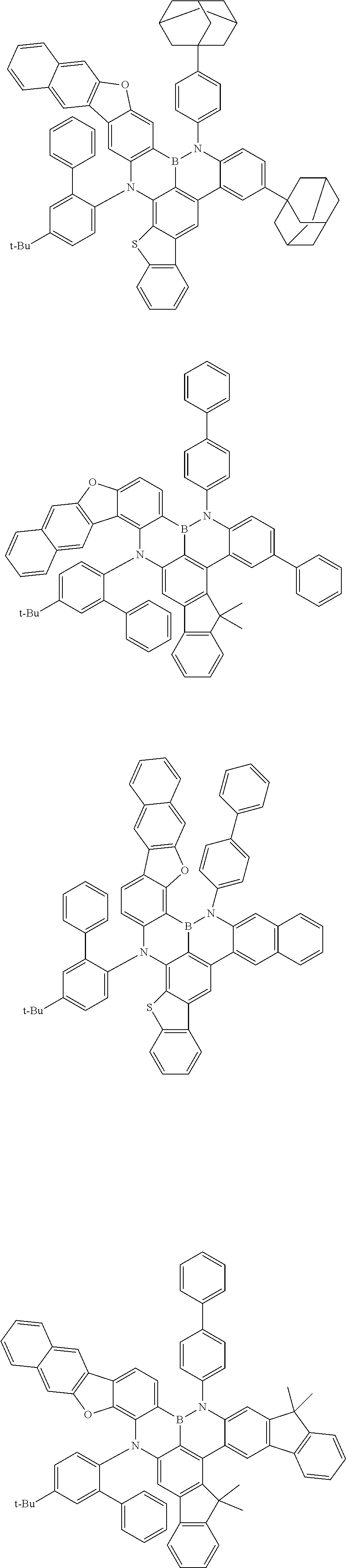 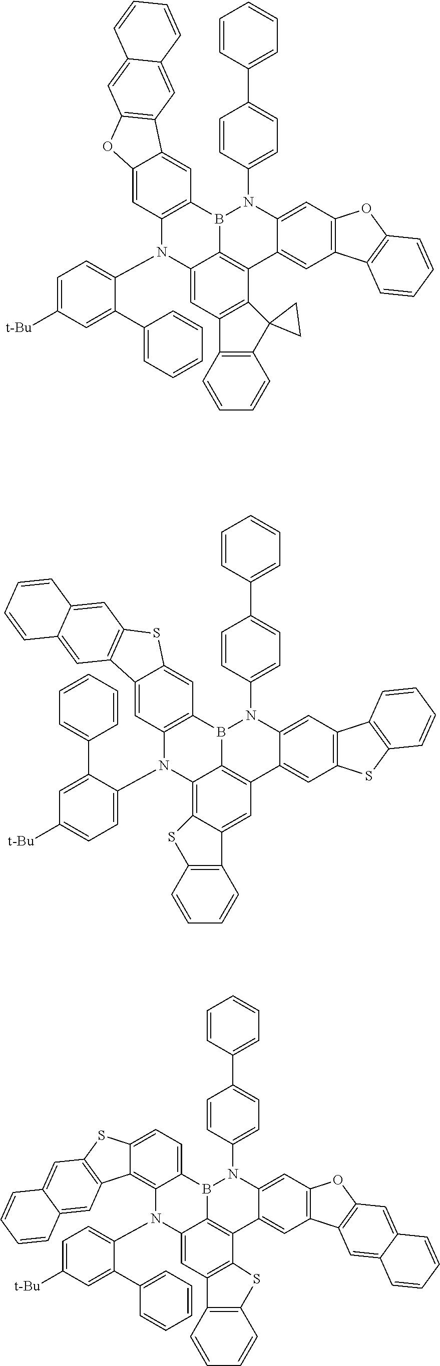 [SMILES: CC(C)(C)c1ccc(N2c3cc4oc5cc6ccccc6cc5c4cc3B3c4c2cc2c(c4-c4cc5c(cc4N3c3ccc(-c4ccccc4)cc3)oc3ccccc35)C3(CC3)c3ccccc3-2)c(-c2ccccc2)c1 ; CC(C)(C)c1ccc(N2c3cc4c(cc3B3c5c(cc6c(sc7ccccc76)c52)-c2cc5sc6ccccc6c5cc2N3c2ccc(-c3ccccc3)cc2)sc2cc3ccccc3cc24)c(-c2ccccc2)c1 ; CC(C)(C)c1ccc(N2c3cc4c(sc5ccccc54)c4c3B(c3ccc5sc6cc7ccccc7cc6c5c32)N(c2ccc(-c3ccccc3)cc2)c2cc3oc5cc6ccccc6cc5c3cc2-4)c(-c2ccccc2)c1] 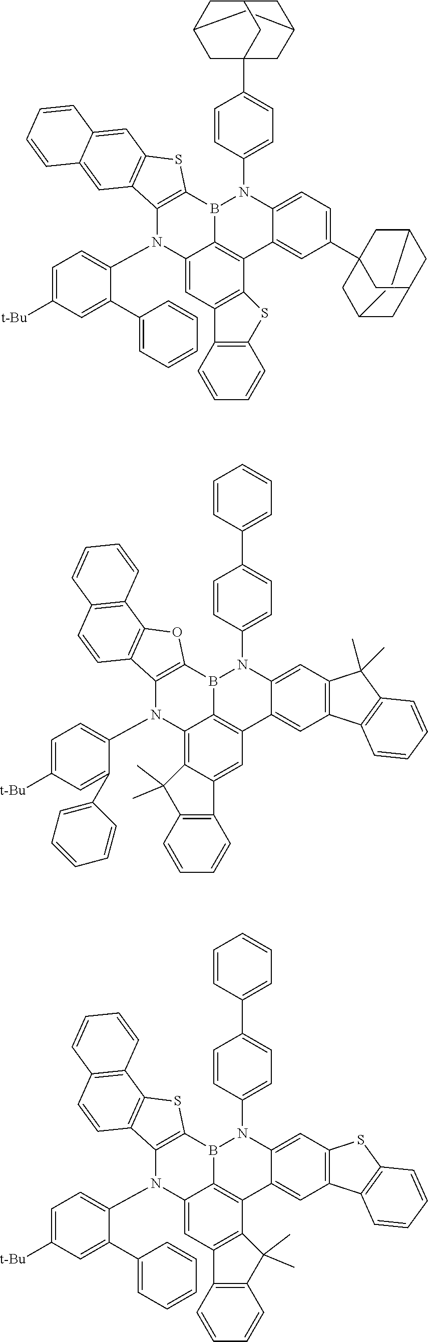 [SMILES: CC(C)(C)c1ccc(N2c3cc4c(sc5ccccc54)c4c3B(c3sc5cc6ccccc6cc5c32)N(c2ccc(C35CC6CC(CC(C6)C3)C5)cc2)c2ccc(C35CC6CC(CC(C6)C3)C5)cc2-4)c(-c2ccccc2)c1 ; CC(C)(C)c1ccc(N2c3c4c(cc5c3C(C)(C)c3ccccc3-5)-c3cc5c(cc3N(c3ccc(-c6ccccc6)cc3)B4c3oc4c(ccc6ccccc64)c32)C(C)(C)c2ccccc2-5)c(-c2ccccc2)c1 ; CC(C)(C)c1ccc(N2c3cc4c(c5c3B(c3sc6c(ccc7ccccc76)c32)N(c2ccc(-c3ccccc3)cc2)c2cc3sc6ccccc6c3cc2-5)C(C)(C)c2ccccc2-4)c(-c2ccccc2)c1] 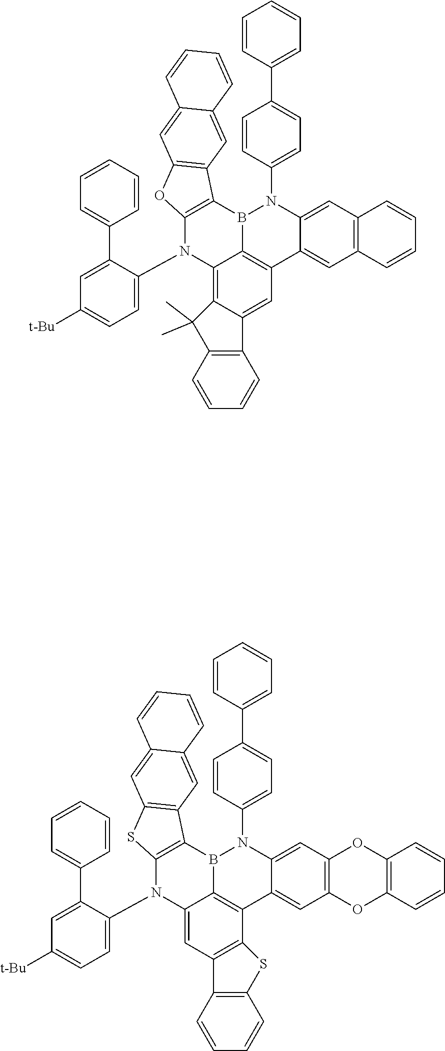 [SMILES: CC(C)(C)c1ccc(N2c3oc4cc5ccccc5cc4c3B3c4c(cc5c(c42)C(C)(C)c2ccccc2-5)-c2cc4ccccc4cc2N3c2ccc(-c3ccccc3)cc2)c(-c2ccccc2)c1 ; CC(C)(C)c1ccc(N2c3cc4c(sc5ccccc54)c4c3B(c3c2sc2cc5ccccc5cc32)N(c2ccc(-c3ccccc3)cc2)c2cc3c(cc2-4)Oc2ccccc2O3)c(-c2ccccc2)c1] 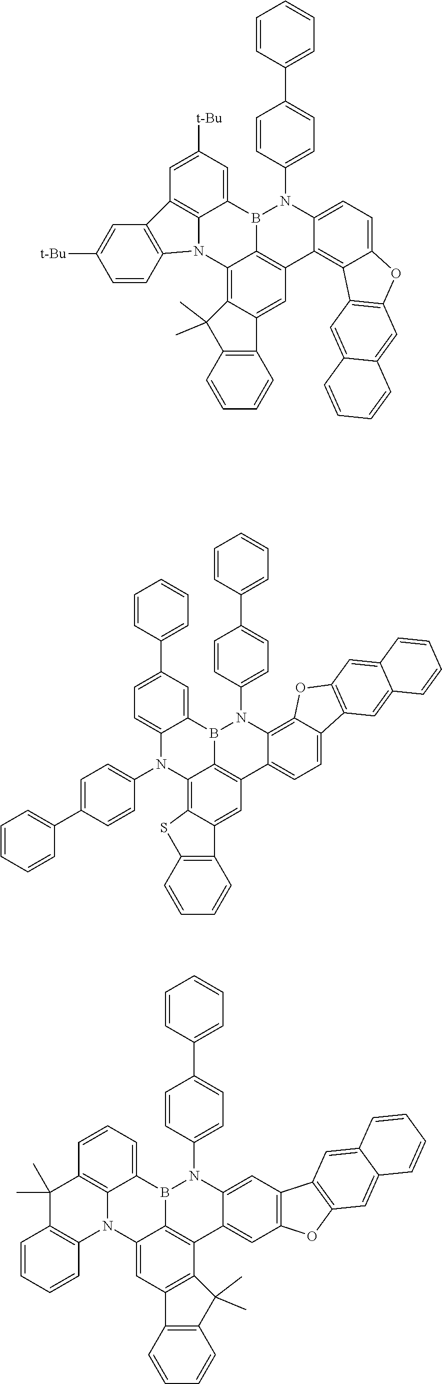 [SMILES: CC(C)(C)c1ccc2c(c1)c1cc(C(C)(C)C)cc3c1n2-c1c2c(cc4c1C(C)(C)c1ccccc1-4)-c1c(ccc4oc5cc6ccccc6cc5c14)N(c1ccc(-c4ccccc4)cc1)B23 ; c1ccc(-c2ccc(N3B4c5cc(-c6ccccc6)ccc5N(c5ccc(-c6ccccc6)cc5)c5c4c(cc4c5sc5ccccc54)-c4ccc5c(oc6cc7ccccc7cc65)c43)cc2)cc1 ; CC1(C)c2ccccc2N2c3cc4c(c5c3B(c3cccc1c32)N(c1ccc(-c2ccccc2)cc1)c1cc2c(cc1-5)oc1cc3ccccc3cc12)C(C)(C)c1ccccc1-4] 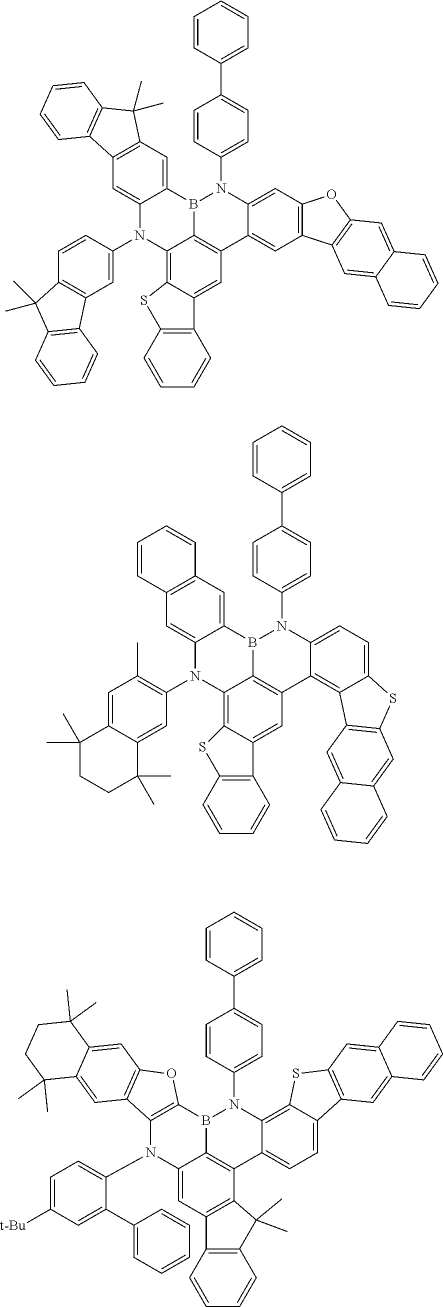 [SMILES: CC1(C)c2ccccc2-c2cc(N3c4cc5c(cc4B4c6c(cc7c(sc8ccccc87)c63)-c3cc6c(cc3N4c3ccc(-c4ccccc4)cc3)oc3cc4ccccc4cc36)C(C)(C)c3ccccc3-5)ccc21 ; Cc1cc2c(cc1N1c3cc4ccccc4cc3B3c4c(cc5c(sc6ccccc65)c41)-c1c(ccc4sc5cc6ccccc6cc5c14)N3c1ccc(-c3ccccc3)cc1)C(C)(C)CCC2(C)C ; CC(C)(C)c1ccc(N2c3cc4c(c5c3B(c3oc6cc7c(cc6c32)C(C)(C)CCC7(C)C)N(c2ccc(-c3ccccc3)cc2)c2c-5ccc3c2sc2cc5ccccc5cc23)C(C)(C)c2ccccc2-4)c(-c2ccccc2)c1] 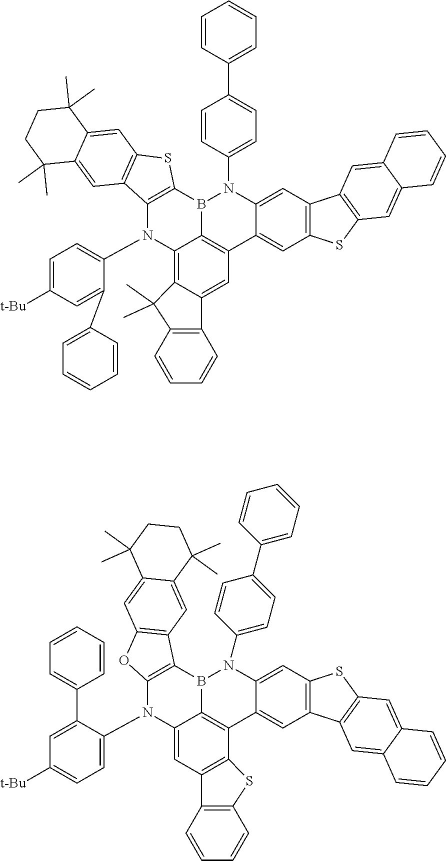 [SMILES: CC(C)(C)c1ccc(N2c3c4c(cc5c3C(C)(C)c3ccccc3-5)-c3cc5sc6cc7ccccc7cc6c5cc3N(c3ccc(-c5ccccc5)cc3)B4c3sc4cc5c(cc4c32)C(C)(C)CCC5(C)C)c(-c2ccccc2)c1 ; CC(C)(C)c1ccc(N2c3cc4c(sc5ccccc54)c4c3B(c3c2oc2cc5c(cc32)C(C)(C)CCC5(C)C)N(c2ccc(-c3ccccc3)cc2)c2cc3sc5cc6ccccc6cc5c3cc2-4)c(-c2ccccc2)c1] 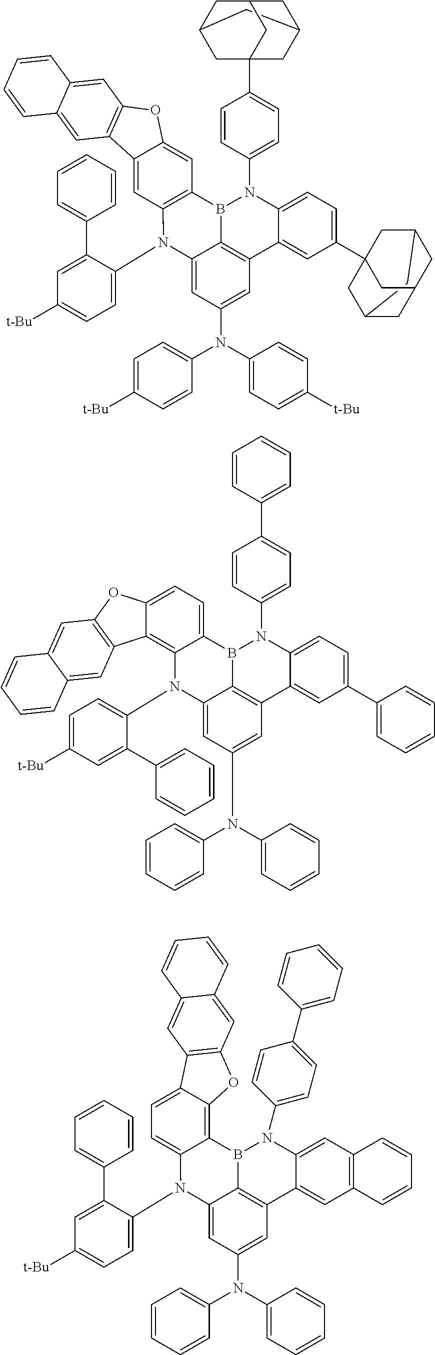 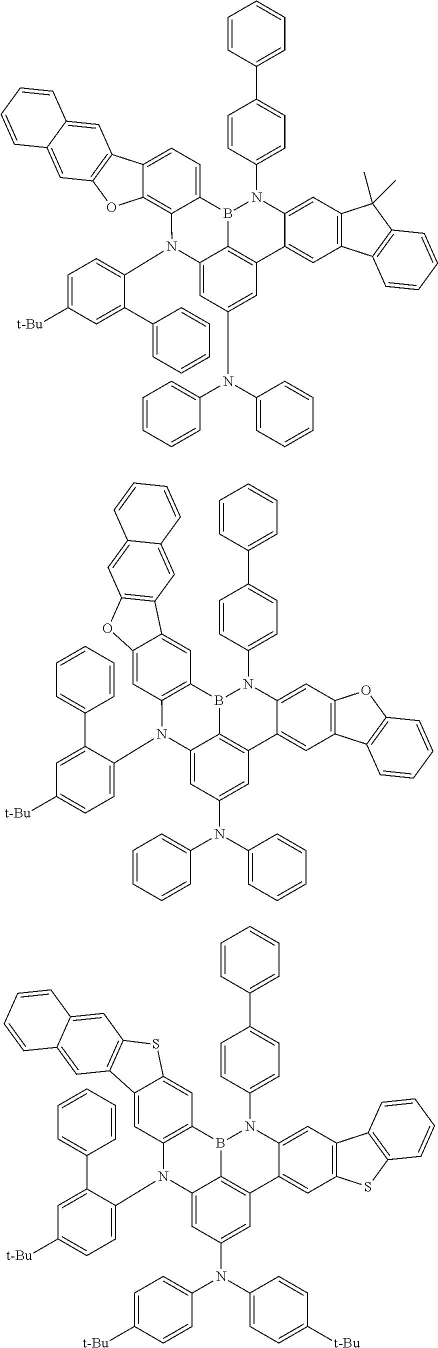 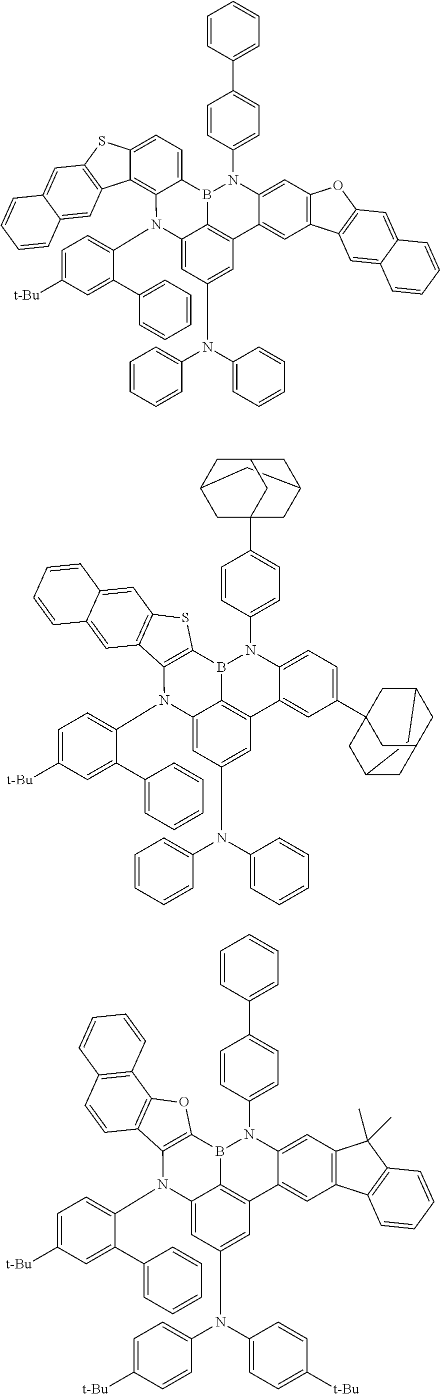 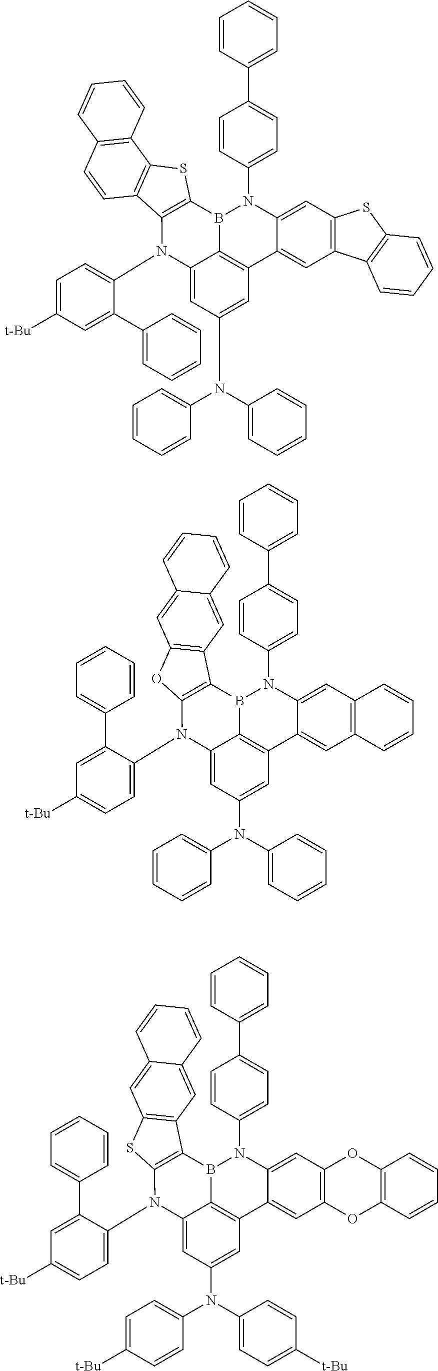 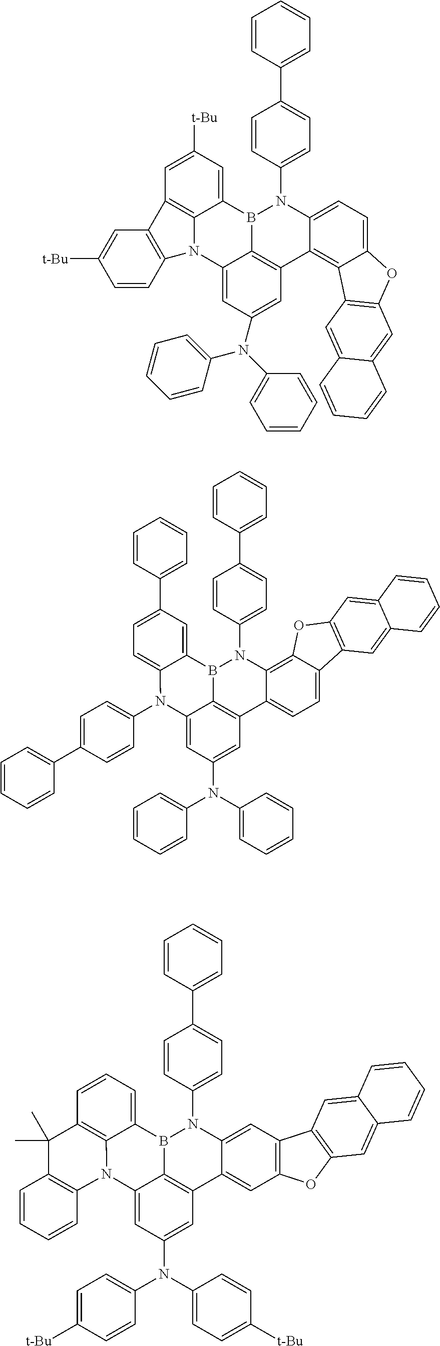 [SMILES: CC(C)(C)c1ccc2c(c1)c1cc(C(C)(C)C)cc3c1n2-c1cc(N(c2ccccc2)c2ccccc2)cc2c1B3N(c1ccc(-c3ccccc3)cc1)c1ccc3oc4cc5ccccc5cc4c3c1-2 ; c1ccc(-c2ccc(N3B4c5cc(-c6ccccc6)ccc5N(c5ccc(-c6ccccc6)cc5)c5cc(N(c6ccccc6)c6ccccc6)cc(c54)-c4ccc5c(oc6cc7ccccc7cc65)c43)cc2)cc1 ; CC(C)(C)c1ccc(N(c2ccc(C(C)(C)C)cc2)c2cc3c4c(c2)N2c5ccccc5C(C)(C)c5cccc(c52)B4N(c2ccc(-c4ccccc4)cc2)c2cc4c(cc2-3)oc2cc3ccccc3cc24)cc1] 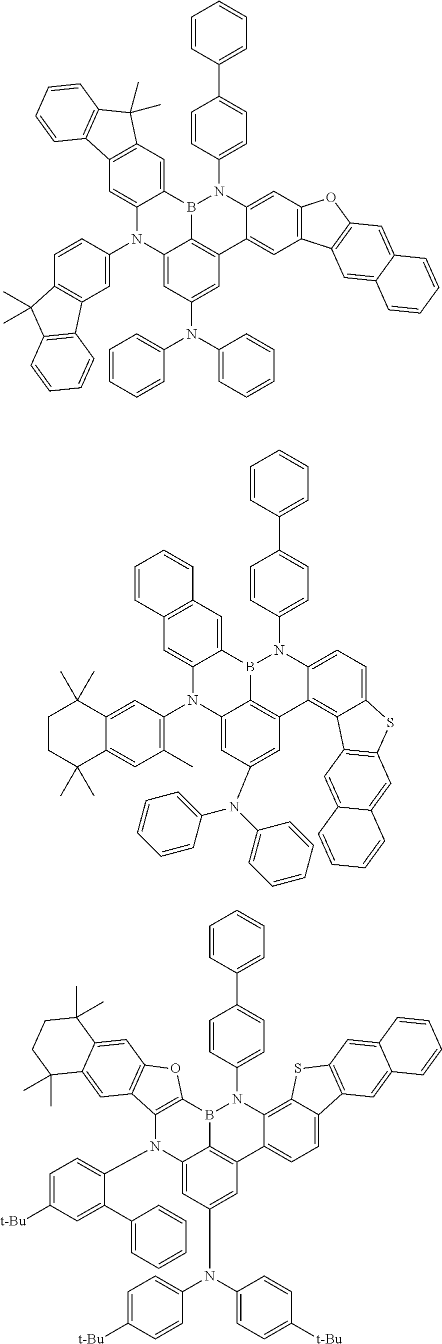 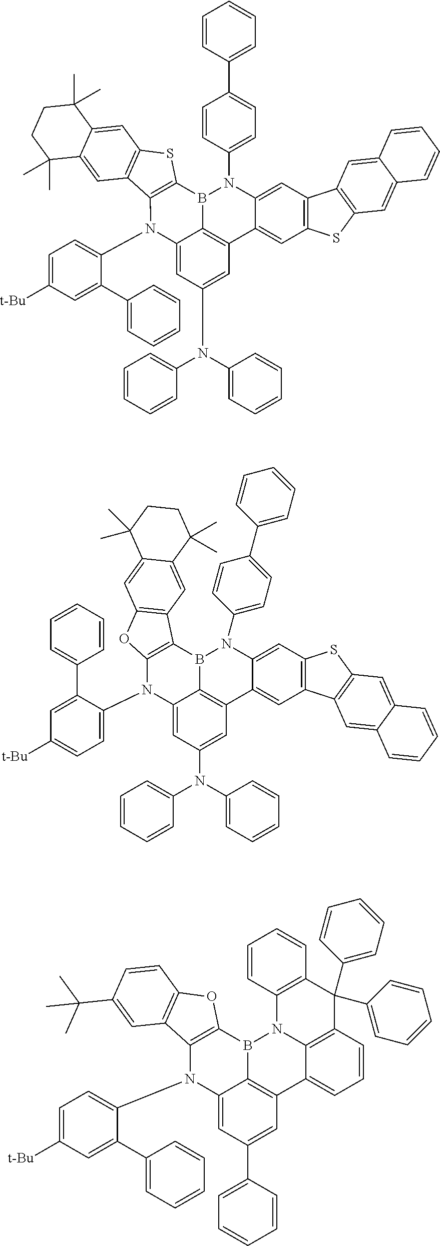 [SMILES: CC(C)(C)c1ccc(N2c3cc(N(c4ccccc4)c4ccccc4)cc4c3B(c3sc5cc6c(cc5c32)C(C)(C)CCC6(C)C)N(c2ccc(-c3ccccc3)cc2)c2cc3c(cc2-4)sc2cc4ccccc4cc23)c(-c2ccccc2)c1 ; CC(C)(C)c1ccc(N2c3cc(N(c4ccccc4)c4ccccc4)cc4c3B(c3c2oc2cc5c(cc32)C(C)(C)CCC5(C)C)N(c2ccc(-c3ccccc3)cc2)c2cc3sc5cc6ccccc6cc5c3cc2-4)c(-c2ccccc2)c1 ; CC(C)(C)c1ccc(N2c3cc(-c4ccccc4)cc4c3B(c3oc5ccc(C(C)(C)C)cc5c32)N2c3ccccc3C(c3ccccc3)(c3ccccc3)c3cccc-4c32)c(-c2ccccc2)c1] 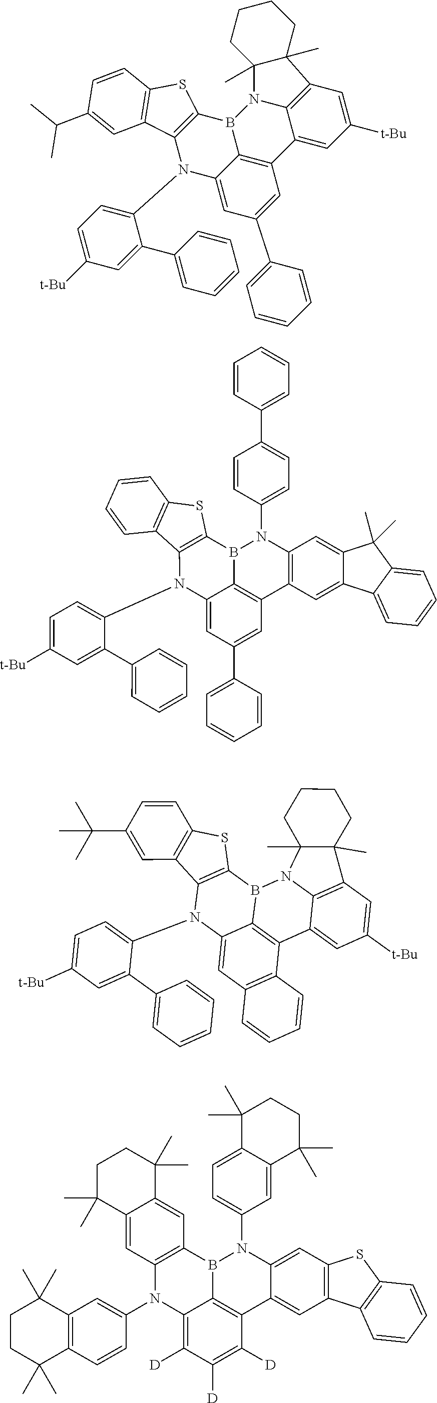 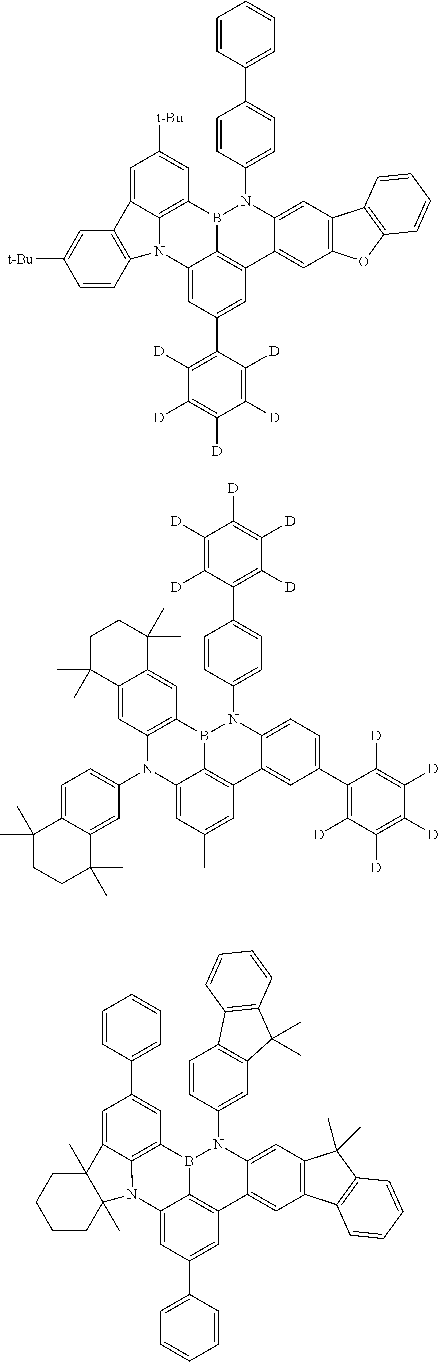 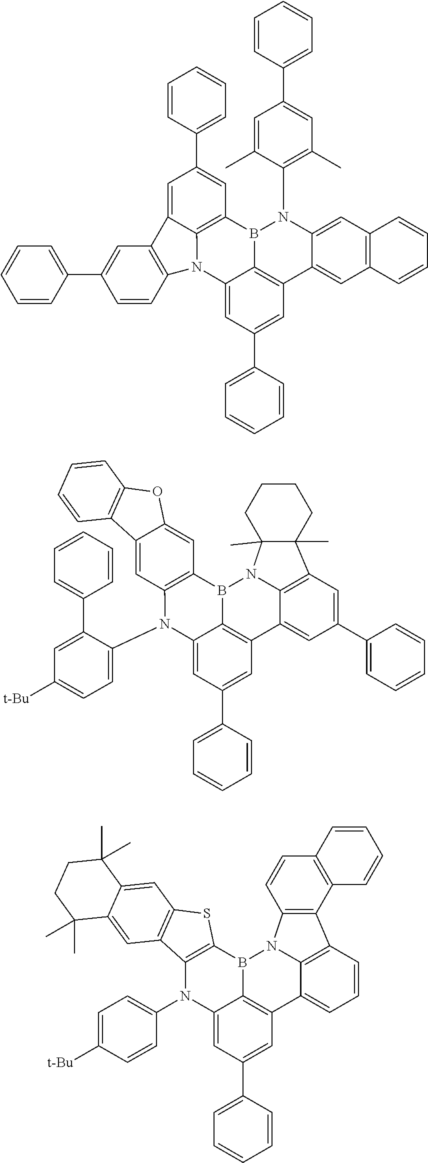 [SMILES: Cc1cc(-c2ccccc2)cc(C)c1N1B2c3c(cc(-c4ccccc4)cc3-n3c4ccc(-c5ccccc5)cc4c4cc(-c5ccccc5)cc2c43)-c2cc3ccccc3cc21 ; CC(C)(C)c1ccc(N2c3cc4c(cc3B3c5c(cc(-c6ccccc6)cc52)-c2cc(-c5ccccc5)cc5c2N3C2(C)CCCCC52C)oc2ccccc24)c(-c2ccccc2)c1 ; CC(C)(C)c1ccc(N2c3cc(-c4ccccc4)cc4c3B(c3sc5cc6c(cc5c32)C(C)(C)CCC6(C)C)n2c3ccc5ccccc5c3c3cccc-4c32)cc1] 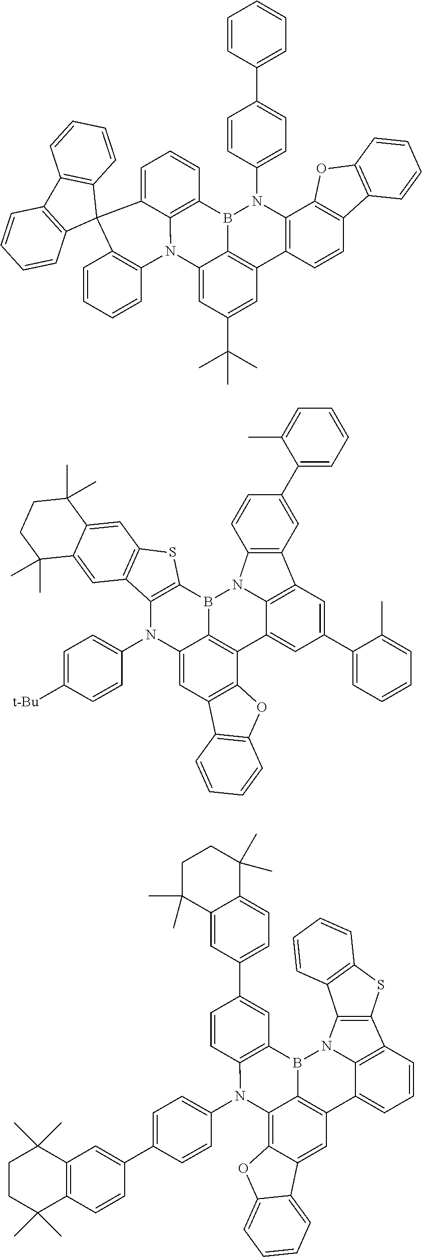 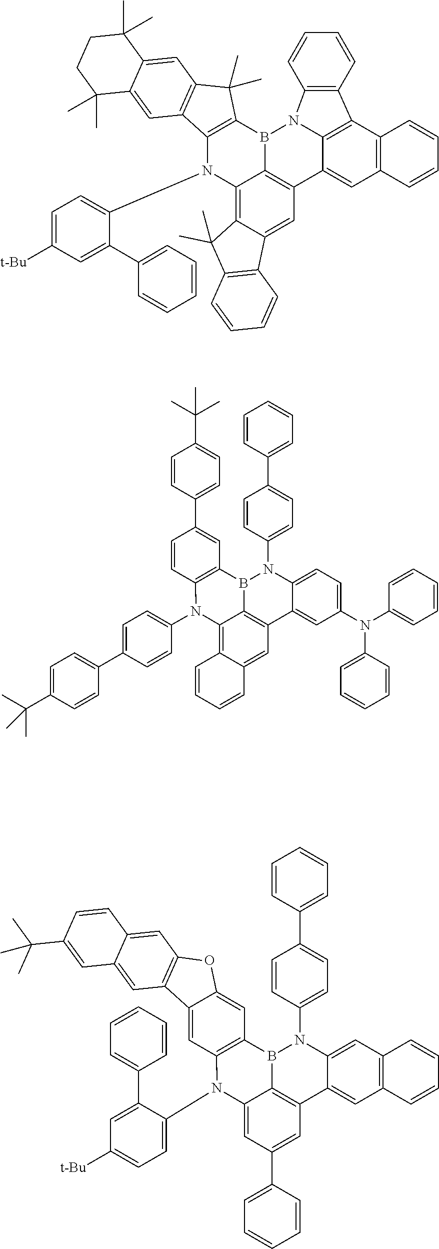 [SMILES: CC(C)(C)c1ccc(N2C3=C(B4c5c(cc6c(c52)C(C)(C)c2ccccc2-6)-c2cc5ccccc5c5c6ccccc6n4c25)C(C)(C)c2cc4c(cc23)C(C)(C)CCC4(C)C)c(-c2ccccc2)c1 ; CC(C)(C)c1ccc(-c2ccc(N3c4ccc(-c5ccc(C(C)(C)C)cc5)cc4B4c5c(cc6ccccc6c53)-c3cc(N(c5ccccc5)c5ccccc5)ccc3N4c3ccc(-c4ccccc4)cc3)cc2)cc1 ; CC(C)(C)c1ccc(N2c3cc4c(cc3B3c5c(cc(-c6ccccc6)cc52)-c2cc5ccccc5cc2N3c2ccc(-c3ccccc3)cc2)oc2cc3ccc(C(C)(C)C)cc3cc24)c(-c2ccccc2)c1] 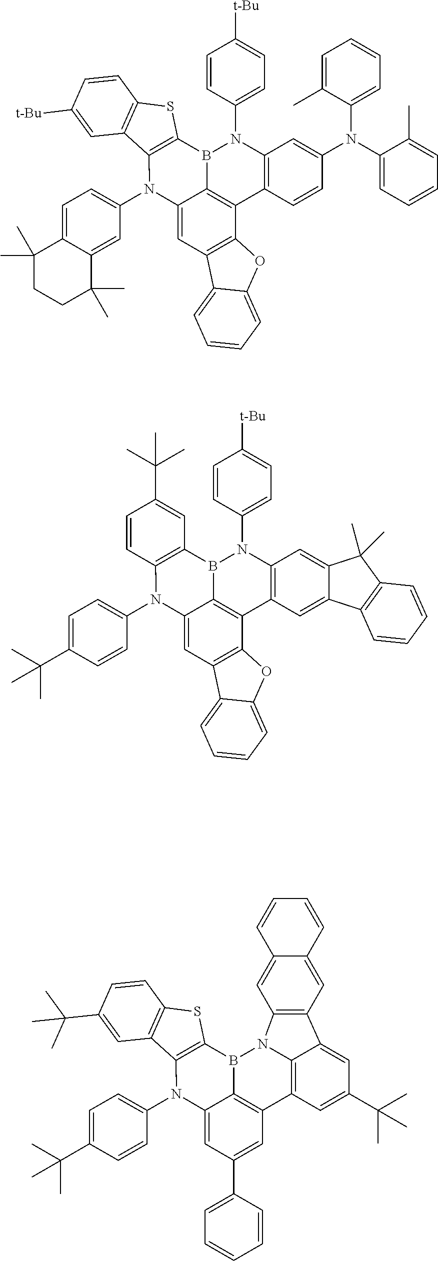 [SMILES: Cc1ccccc1N(c1ccc2c(c1)N(c1ccc(C(C)(C)C)cc1)B1c3sc4ccc(C(C)(C)C)cc4c3N(c3ccc4c(c3)C(C)(C)CCC4(C)C)c3cc4c(oc5ccccc54)c-2c31)c1ccccc1C ; CC(C)(C)c1ccc(N2B3c4cc(C(C)(C)C)ccc4N(c4ccc(C(C)(C)C)cc4)c4cc5c(oc6ccccc65)c(c43)-c3cc4c(cc32)C(C)(C)c2ccccc2-4)cc1 ; CC(C)(C)c1ccc(N2c3cc(-c4ccccc4)cc4c3B(c3sc5ccc(C(C)(C)C)cc5c32)n2c3cc5ccccc5cc3c3cc(C(C)(C)C)cc-4c32)cc1] 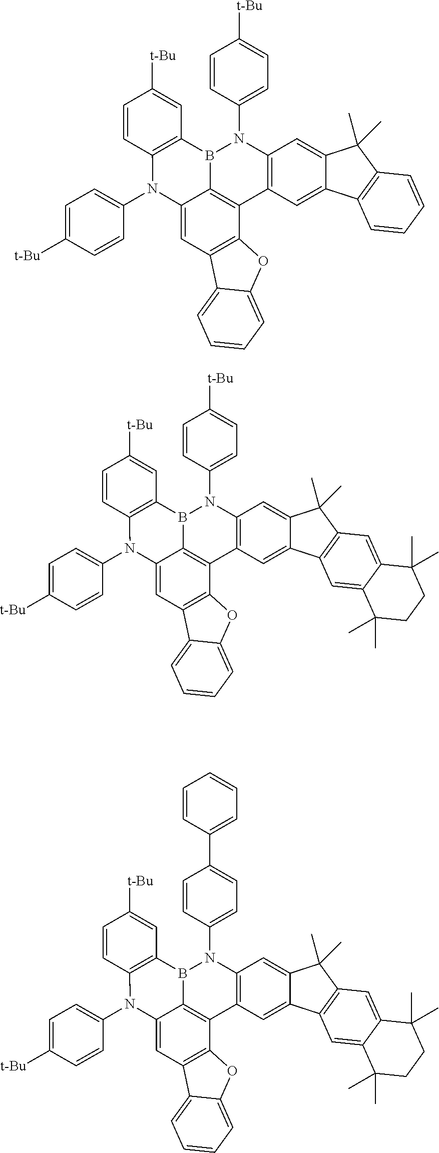 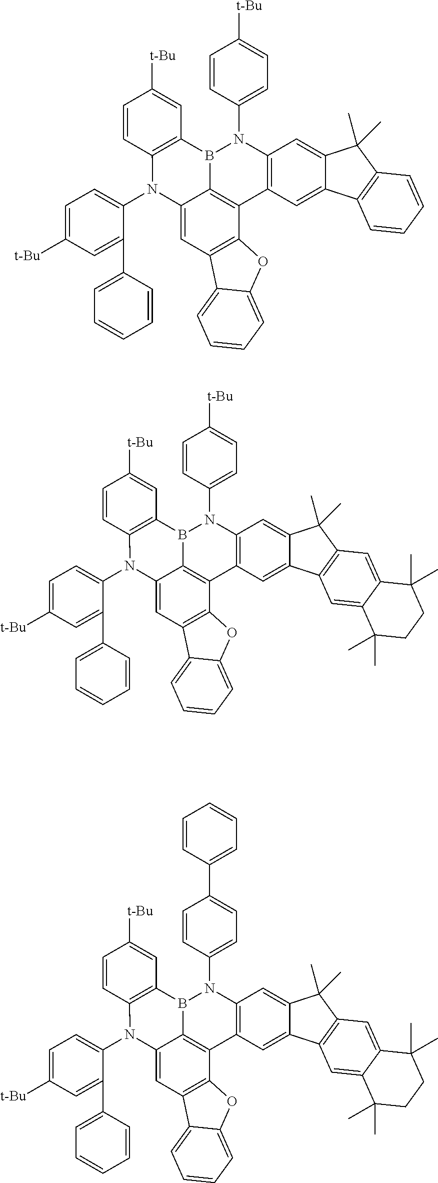 [SMILES: CC(C)(C)c1ccc(N2B3c4cc(C(C)(C)C)ccc4N(c4ccc(C(C)(C)C)cc4-c4ccccc4)c4cc5c(oc6ccccc65)c(c43)-c3cc4c(cc32)C(C)(C)c2ccccc2-4)cc1 ; CC(C)(C)c1ccc(N2B3c4cc(C(C)(C)C)ccc4N(c4ccc(C(C)(C)C)cc4-c4ccccc4)c4cc5c(oc6ccccc65)c(c43)-c3cc4c(cc32)C(C)(C)c2cc3c(cc2-4)C(C)(C)CCC3(C)C)cc1 ; CC(C)(C)c1ccc2c(c1)B1c3c(cc4c(oc5ccccc54)c3-c3cc4c(cc3N1c1ccc(-c3ccccc3)cc1)C(C)(C)c1cc3c(cc1-4)C(C)(C)CCC3(C)C)N2c1ccc(C(C)(C)C)cc1-c1ccccc1] 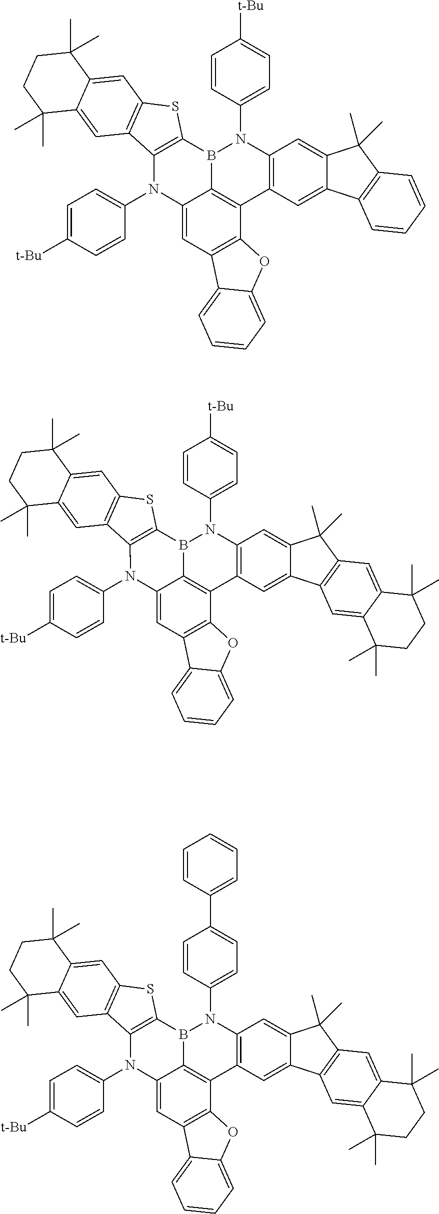 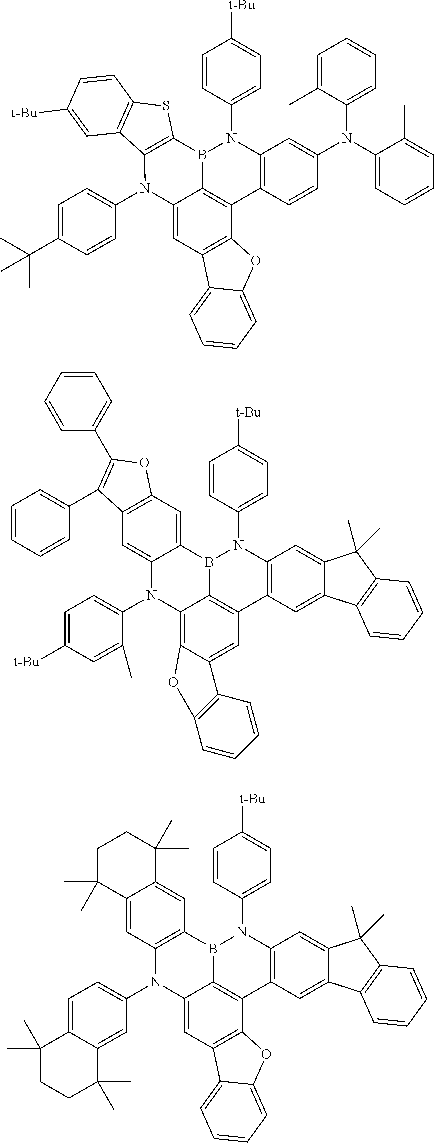 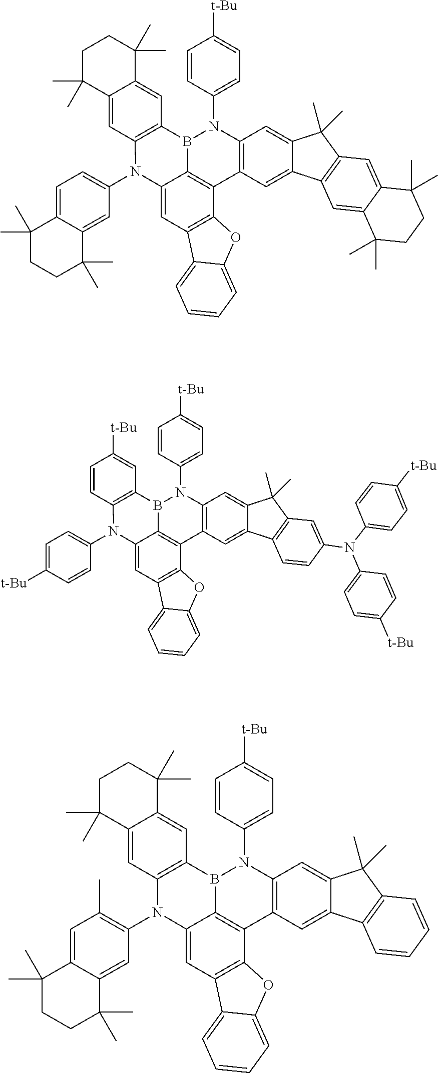 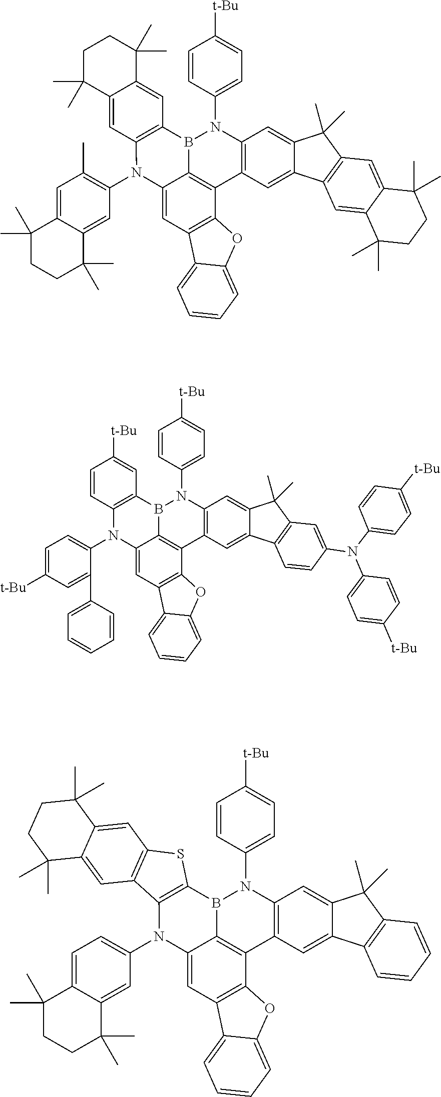 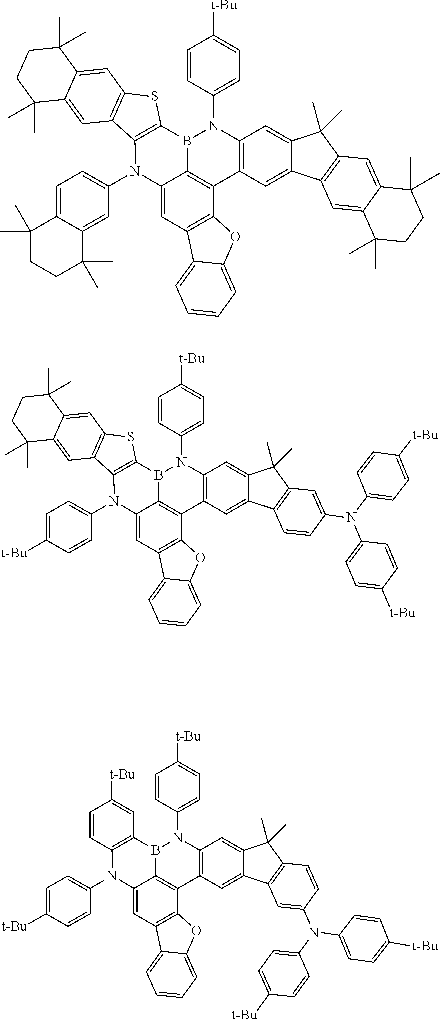 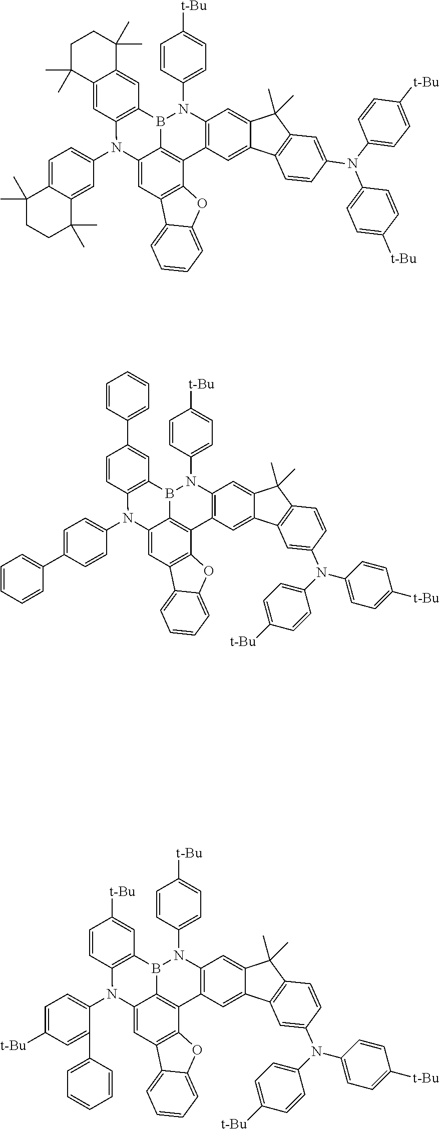 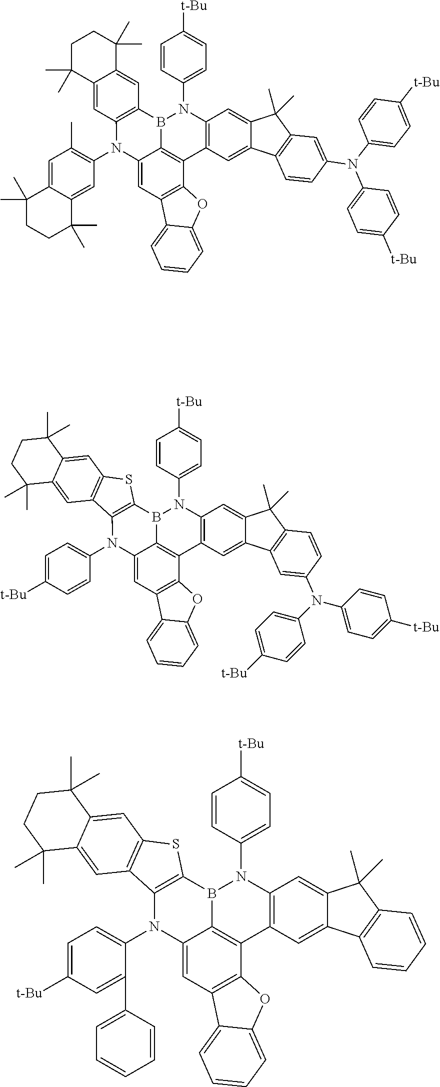 [SMILES: Cc1cc2c(cc1N1c3cc4c(cc3B3c5c1cc1c(oc6ccccc61)c5-c1cc5c(cc1N3c1ccc(C(C)(C)C)cc1)C(C)(C)c1cc(N(c3ccc(C(C)(C)C)cc3)c3ccc(C(C)(C)C)cc3)ccc1-5)C(C)(C)CCC4(C)C)C(C)(C)CCC2(C)C ; CC(C)(C)c1ccc(N2B3c4sc5cc6c(cc5c4N(c4ccc(C(C)(C)C)cc4)c4cc5c(oc7ccccc75)c(c43)-c3cc4c(cc32)C(C)(C)c2ccc(N(c3ccc(C(C)(C)C)cc3)c3ccc(C(C)(C)C)cc3)cc2-4)C(C)(C)CCC6(C)C)cc1 ; CC(C)(C)c1ccc(N2B3c4sc5cc6c(cc5c4N(c4ccc(C(C)(C)C)cc4-c4ccccc4)c4cc5c(oc7ccccc75)c(c43)-c3cc4c(cc32)C(C)(C)c2ccccc2-4)C(C)(C)CCC6(C)C)cc1] 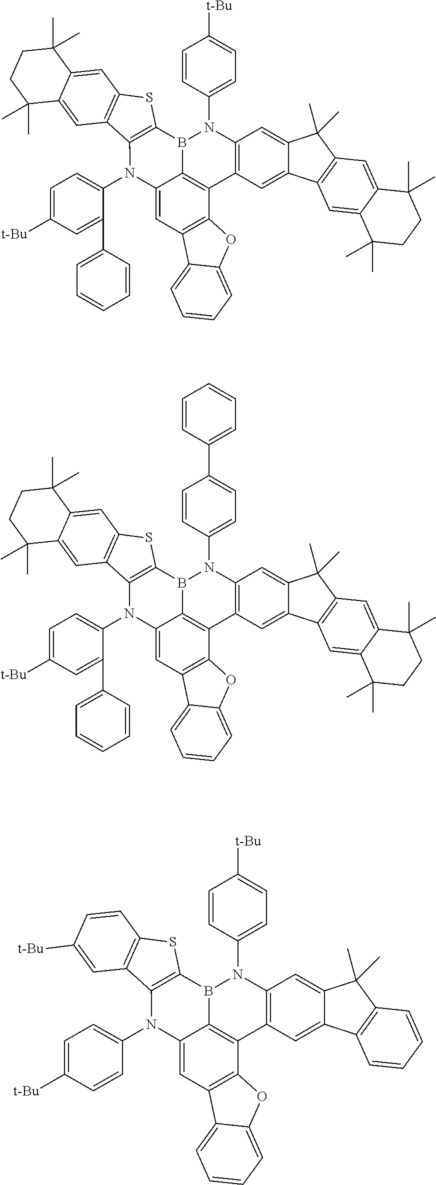 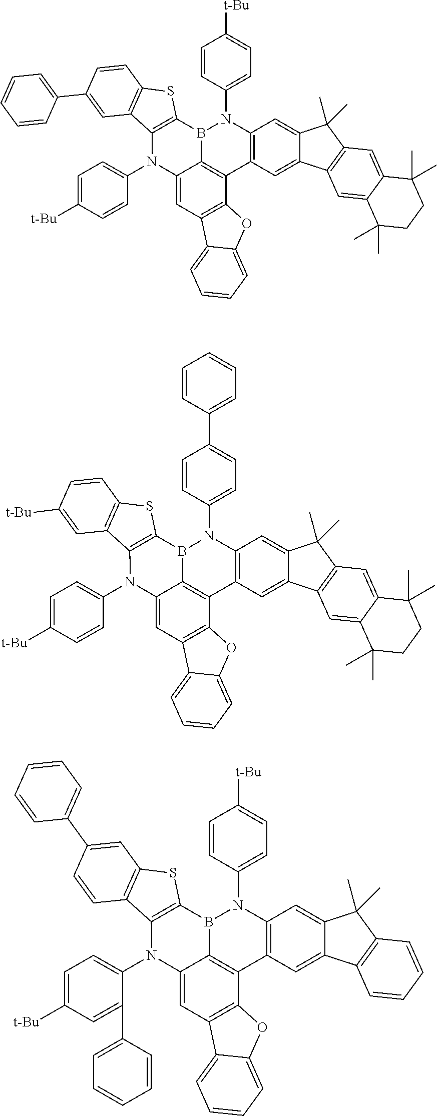 [SMILES: CC(C)(C)c1ccc(N2B3c4sc5ccc(-c6ccccc6)cc5c4N(c4ccc(C(C)(C)C)cc4)c4cc5c(oc6ccccc65)c(c43)-c3cc4c(cc32)C(C)(C)c2cc3c(cc2-4)C(C)(C)CCC3(C)C)cc1 ; CC(C)(C)c1ccc(N2c3cc4c(oc5ccccc54)c4c3B(c3sc5ccc(C(C)(C)C)cc5c32)N(c2ccc(-c3ccccc3)cc2)c2cc3c(cc2-4)-c2cc4c(cc2C3(C)C)C(C)(C)CCC4(C)C)cc1 ; CC(C)(C)c1ccc(N2B3c4sc5cc(-c6ccccc6)ccc5c4N(c4ccc(C(C)(C)C)cc4-c4ccccc4)c4cc5c(oc6ccccc65)c(c43)-c3cc4c(cc32)C(C)(C)c2ccccc2-4)cc1] 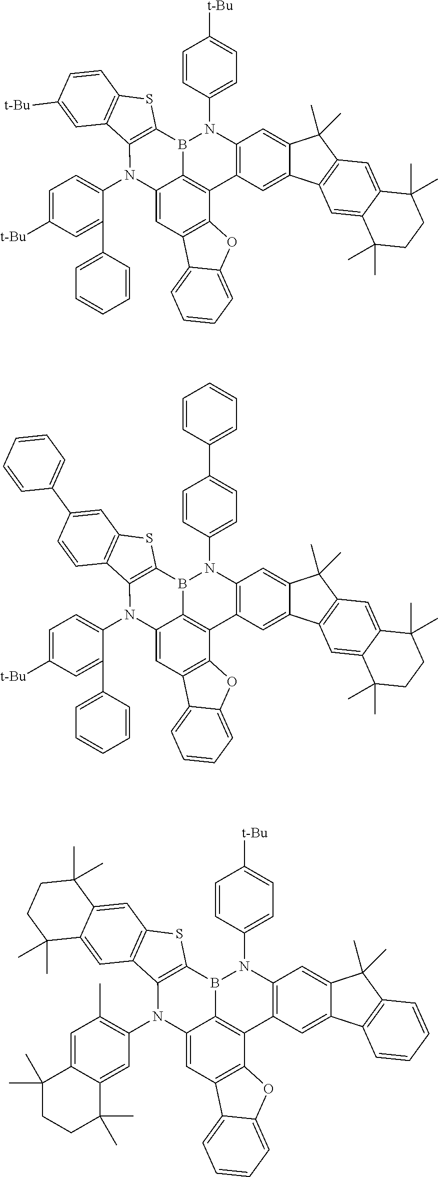 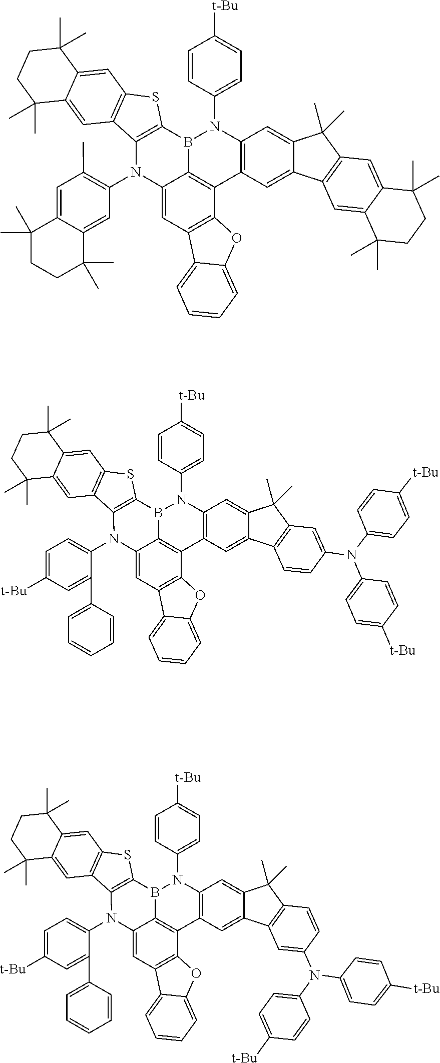 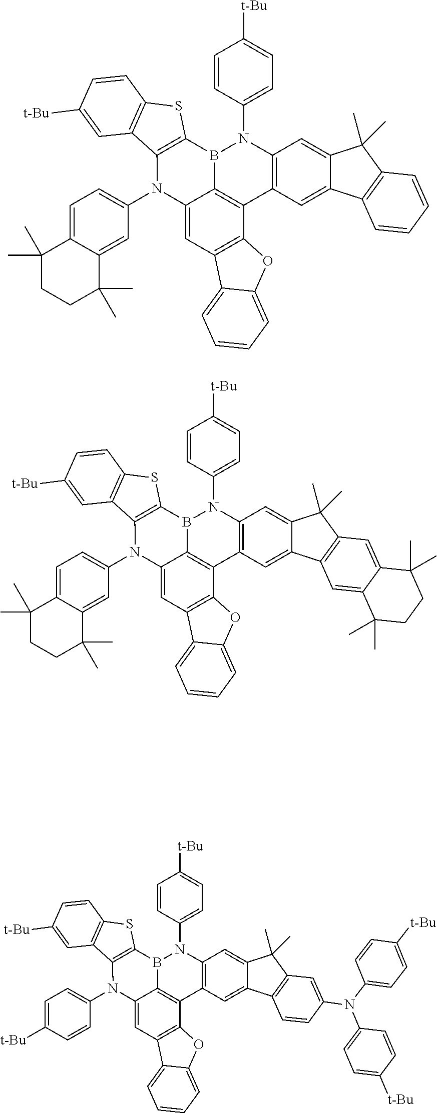 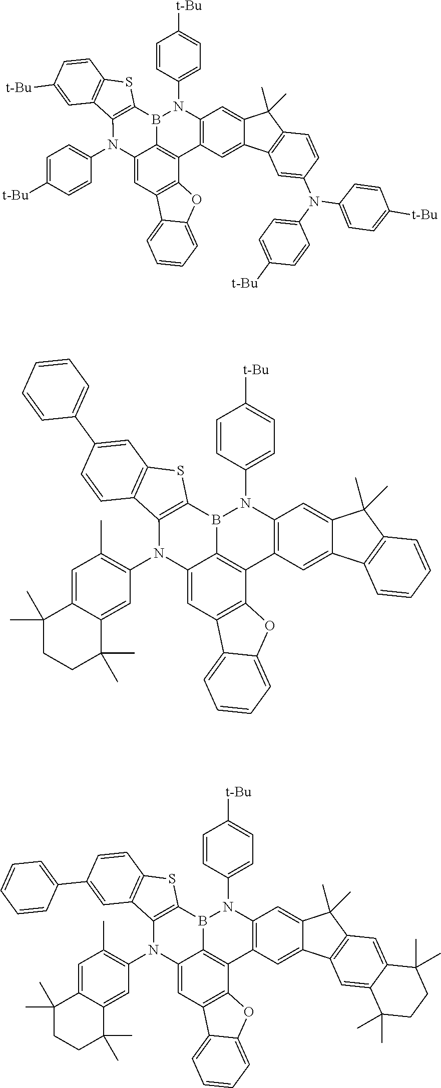 [SMILES: CC(C)(C)c1ccc(N2B3c4sc5ccc(C(C)(C)C)cc5c4N(c4ccc(C(C)(C)C)cc4)c4cc5c(oc6ccccc65)c(c43)-c3cc4c(cc32)C(C)(C)c2ccc(N(c3ccc(C(C)(C)C)cc3)c3ccc(C(C)(C)C)cc3)cc2-4)cc1 ; Cc1cc2c(cc1N1c3cc4c(oc5ccccc54)c4c3B(c3sc5cc(-c6ccccc6)ccc5c31)N(c1ccc(C(C)(C)C)cc1)c1cc3c(cc1-4)-c1ccccc1C3(C)C)C(C)(C)CCC2(C)C ; Cc1cc2c(cc1N1c3cc4c(oc5ccccc54)c4c3B(c3sc5ccc(-c6ccccc6)cc5c31)N(c1ccc(C(C)(C)C)cc1)c1cc3c(cc1-4)-c1cc4c(cc1C3(C)C)C(C)(C)CCC4(C)C)C(C)(C)CCC2(C)C] 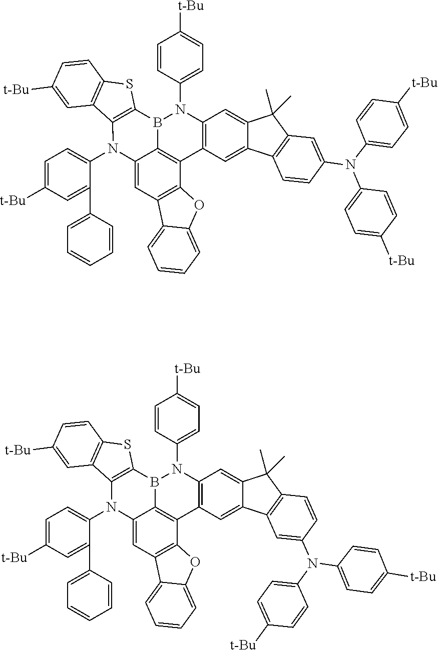 [SMILES: CC(C)(C)c1ccc(N2B3c4sc5ccc(C(C)(C)C)cc5c4N(c4ccc(C(C)(C)C)cc4-c4ccccc4)c4cc5c(oc6ccccc65)c(c43)-c3cc4c(cc32)C(C)(C)c2cc(N(c3ccc(C(C)(C)C)cc3)c3ccc(C(C)(C)C)cc3)ccc2-4)cc1 ; CC(C)(C)c1ccc(N2B3c4sc5ccc(C(C)(C)C)cc5c4N(c4ccc(C(C)(C)C)cc4-c4ccccc4)c4cc5c(oc6ccccc65)c(c43)-c3cc4c(cc32)C(C)(C)c2ccc(N(c3ccc(C(C)(C)C)cc3)c3ccc(C(C)(C)C)cc3)cc2-4)cc1] 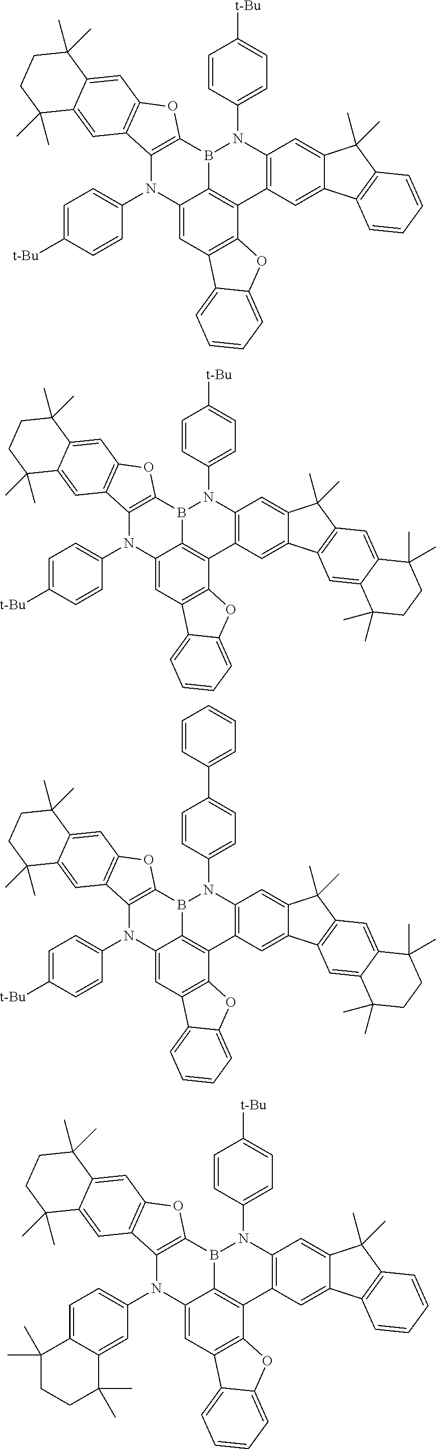 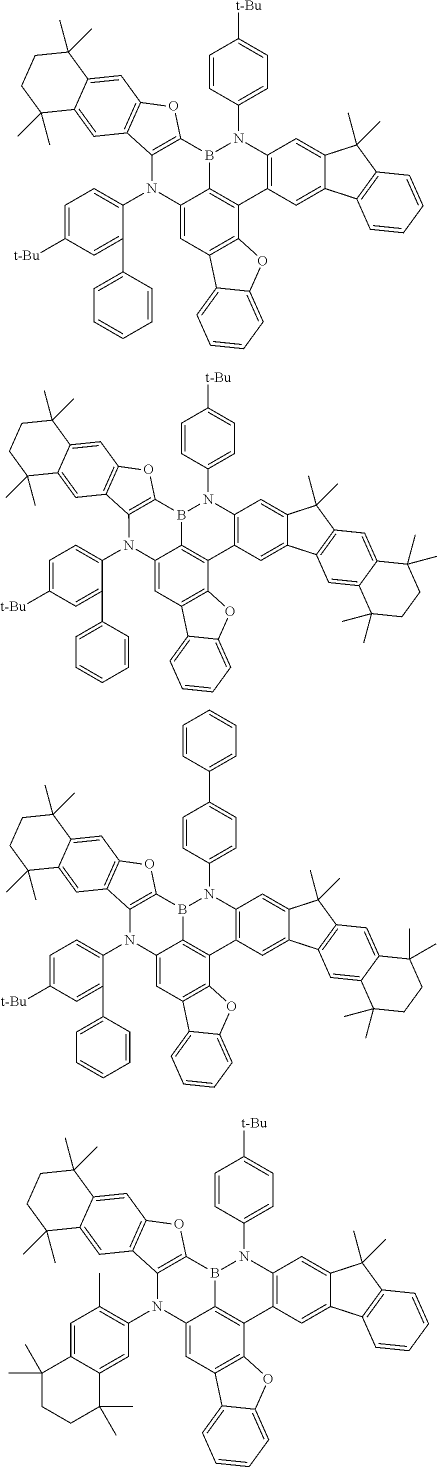 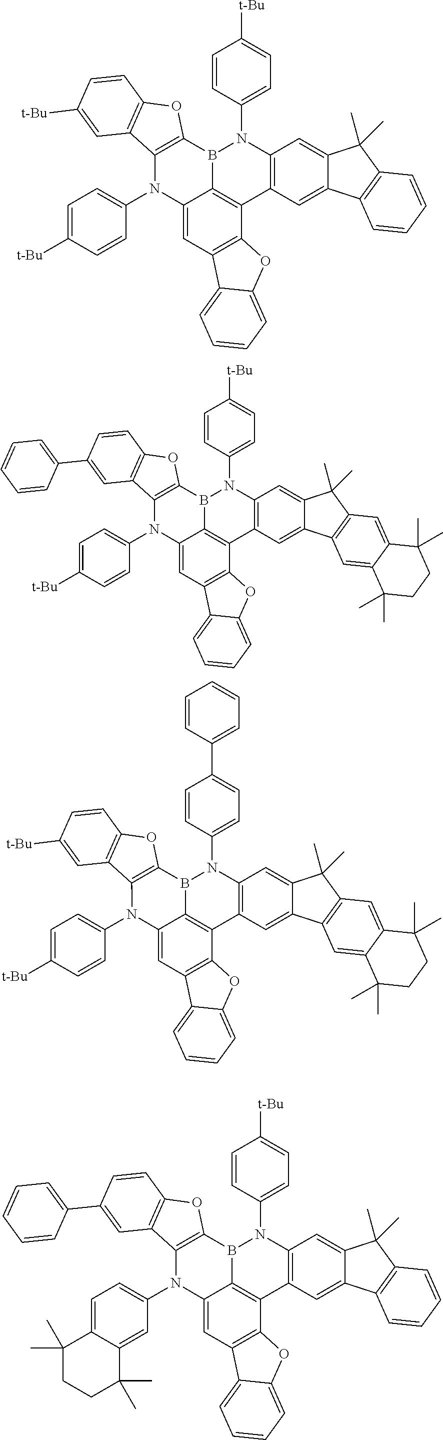 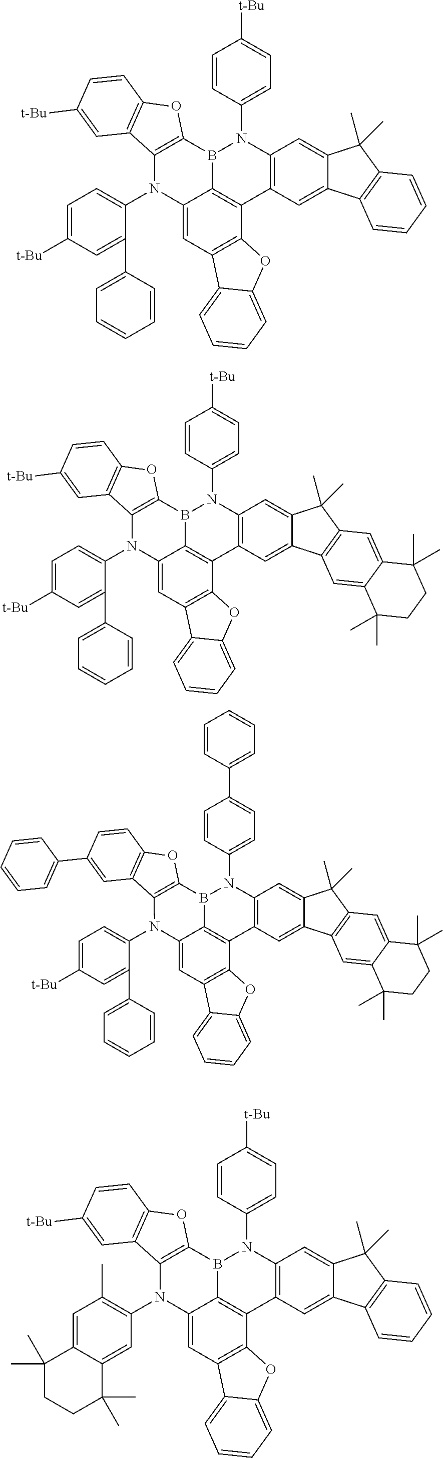 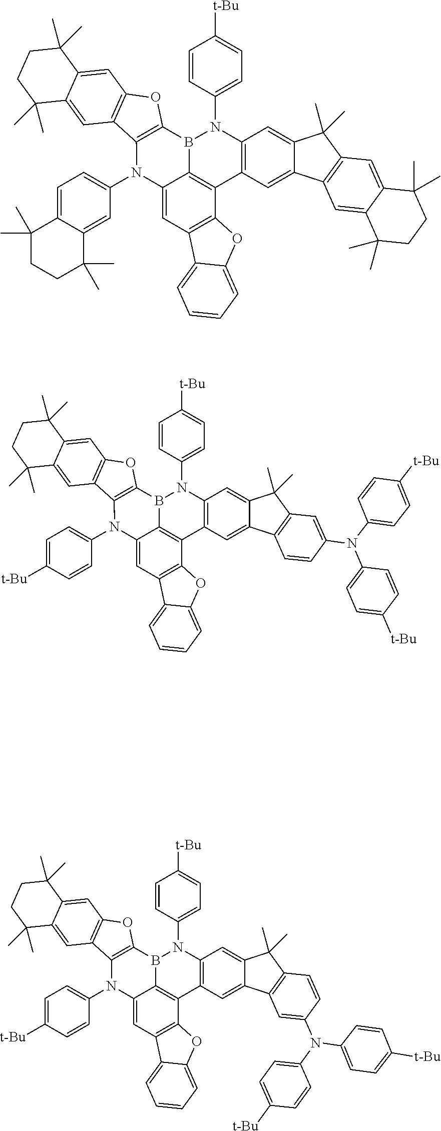 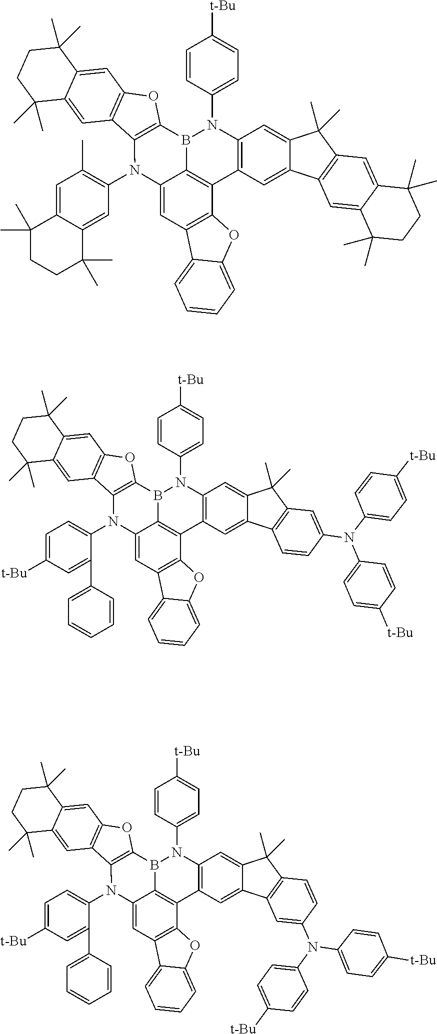 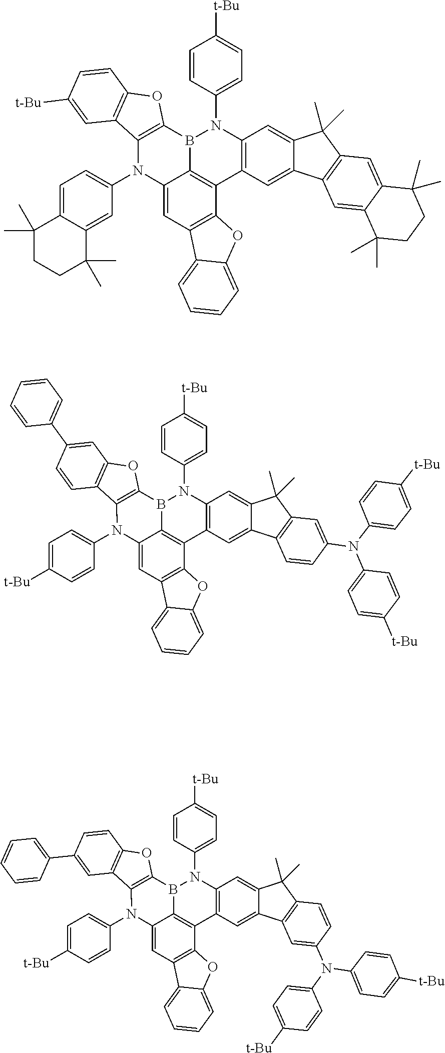 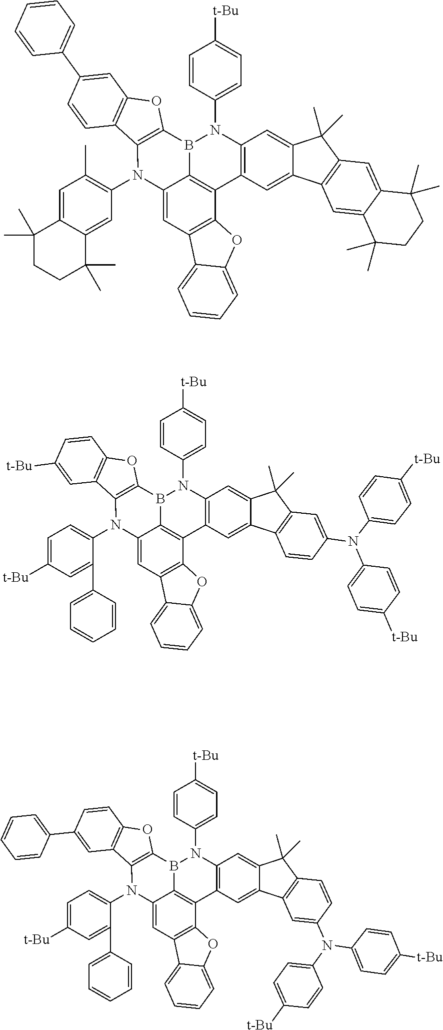 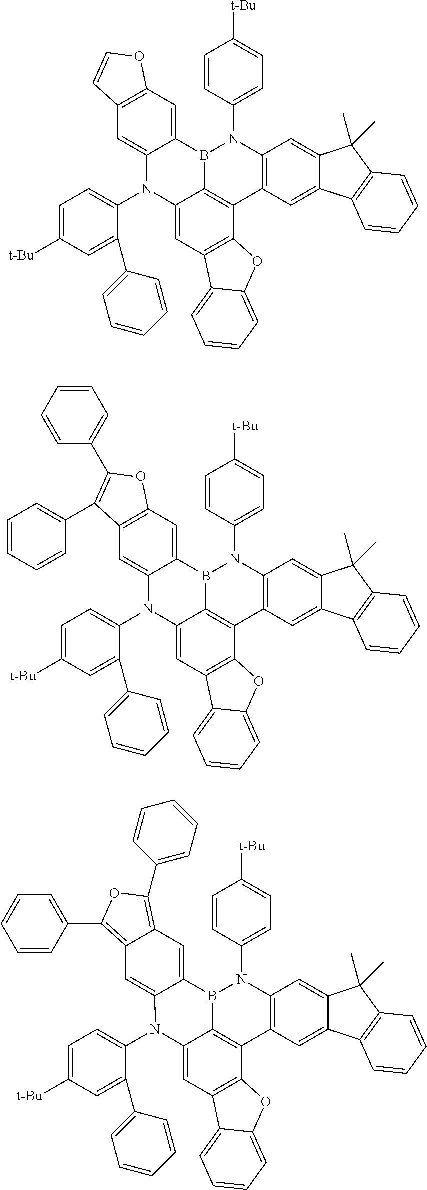 [SMILES: CC(C)(C)c1ccc(N2B3c4cc5occc5cc4N(c4ccc(C(C)(C)C)cc4-c4ccccc4)c4cc5c(oc6ccccc65)c(c43)-c3cc4c(cc32)C(C)(C)c2ccccc2-4)cc1 ; CC(C)(C)c1ccc(N2B3c4cc5oc(-c6ccccc6)c(-c6ccccc6)c5cc4N(c4ccc(C(C)(C)C)cc4-c4ccccc4)c4cc5c(oc6ccccc65)c(c43)-c3cc4c(cc32)C(C)(C)c2ccccc2-4)cc1 ; CC(C)(C)c1ccc(N2B3c4cc5c(-c6ccccc6)oc(-c6ccccc6)c5cc4N(c4ccc(C(C)(C)C)cc4-c4ccccc4)c4cc5c(oc6ccccc65)c(c43)-c3cc4c(cc32)C(C)(C)c2ccccc2-4)cc1] 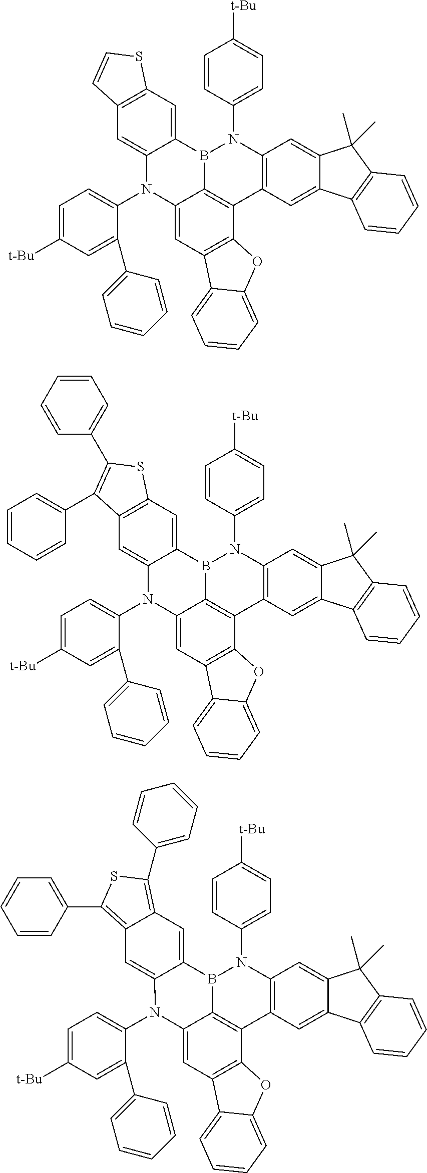 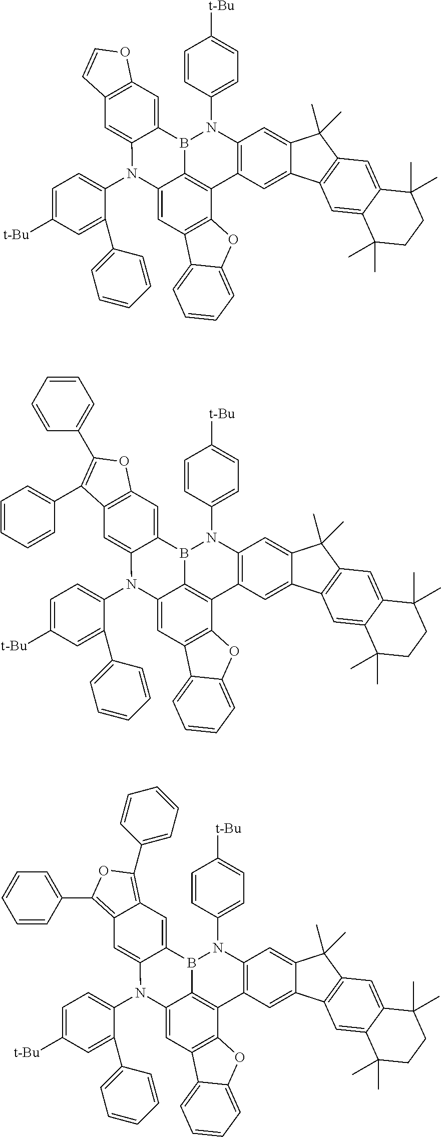 [SMILES: CC(C)(C)c1ccc(N2B3c4cc5occc5cc4N(c4ccc(C(C)(C)C)cc4-c4ccccc4)c4cc5c(oc6ccccc65)c(c43)-c3cc4c(cc32)C(C)(C)c2cc3c(cc2-4)C(C)(C)CCC3(C)C)cc1 ; CC(C)(C)c1ccc(N2B3c4cc5oc(-c6ccccc6)c(-c6ccccc6)c5cc4N(c4ccc(C(C)(C)C)cc4-c4ccccc4)c4cc5c(oc6ccccc65)c(c43)-c3cc4c(cc32)C(C)(C)c2cc3c(cc2-4)C(C)(C)CCC3(C)C)cc1 ; CC(C)(C)c1ccc(N2B3c4cc5c(-c6ccccc6)oc(-c6ccccc6)c5cc4N(c4ccc(C(C)(C)C)cc4-c4ccccc4)c4cc5c(oc6ccccc65)c(c43)-c3cc4c(cc32)C(C)(C)c2cc3c(cc2-4)C(C)(C)CCC3(C)C)cc1] 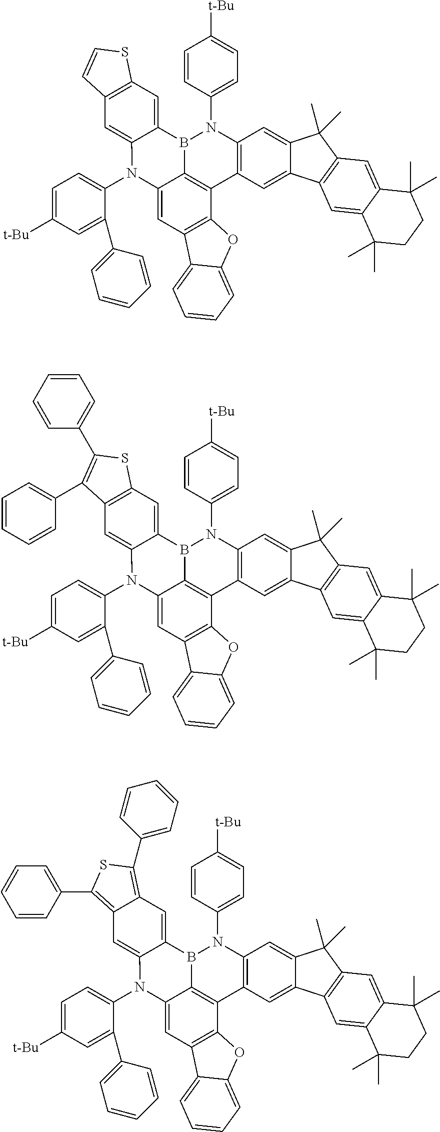 [SMILES: CC(C)(C)c1ccc(N2B3c4cc5sccc5cc4N(c4ccc(C(C)(C)C)cc4-c4ccccc4)c4cc5c(oc6ccccc65)c(c43)-c3cc4c(cc32)C(C)(C)c2cc3c(cc2-4)C(C)(C)CCC3(C)C)cc1 ; CC(C)(C)c1ccc(N2B3c4cc5sc(-c6ccccc6)c(-c6ccccc6)c5cc4N(c4ccc(C(C)(C)C)cc4-c4ccccc4)c4cc5c(oc6ccccc65)c(c43)-c3cc4c(cc32)C(C)(C)c2cc3c(cc2-4)C(C)(C)CCC3(C)C)cc1 ; CC(C)(C)c1ccc(N2B3c4cc5c(-c6ccccc6)sc(-c6ccccc6)c5cc4N(c4ccc(C(C)(C)C)cc4-c4ccccc4)c4cc5c(oc6ccccc65)c(c43)-c3cc4c(cc32)C(C)(C)c2cc3c(cc2-4)C(C)(C)CCC3(C)C)cc1] 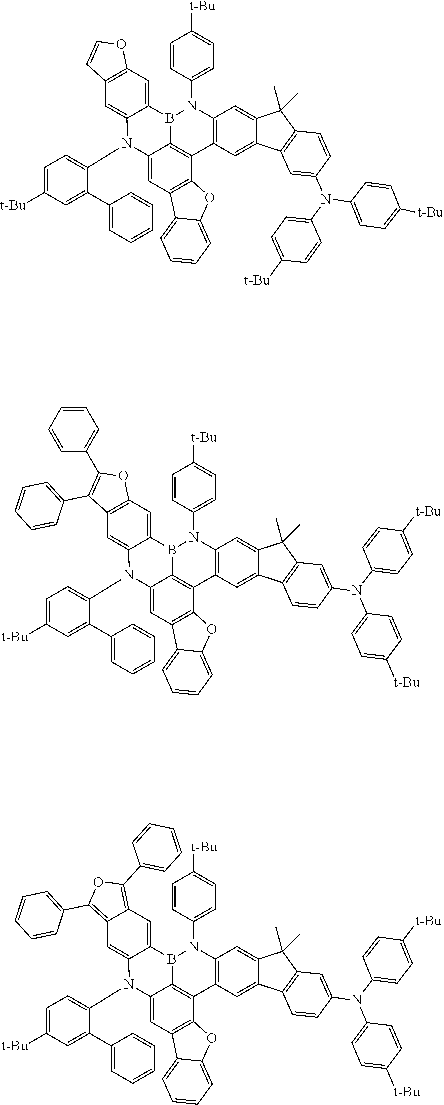 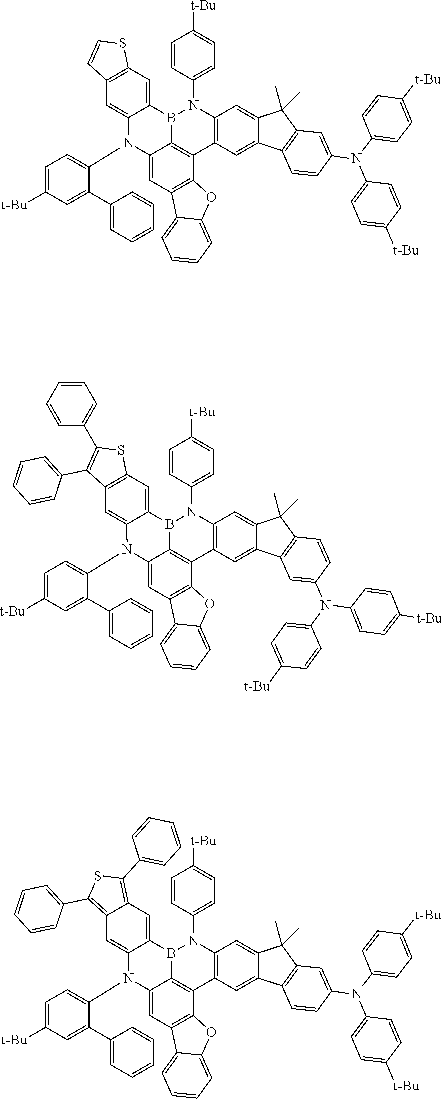 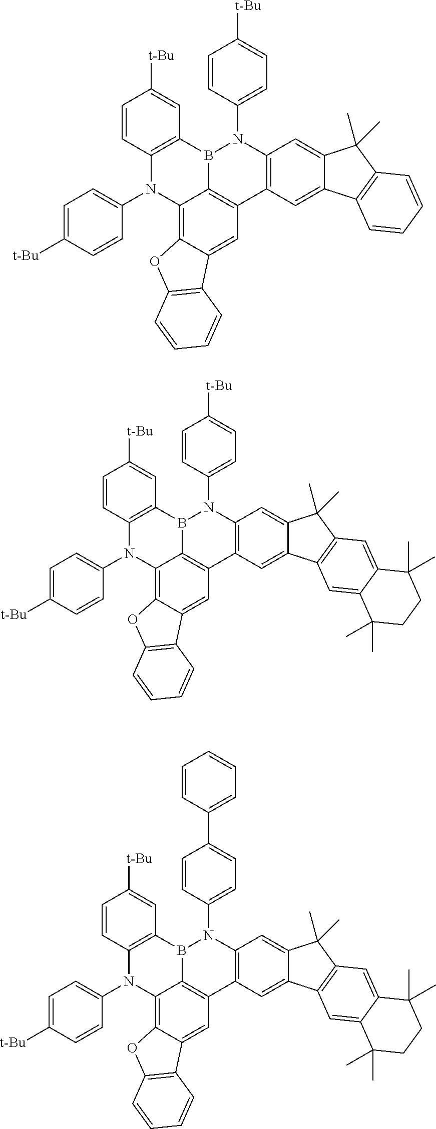 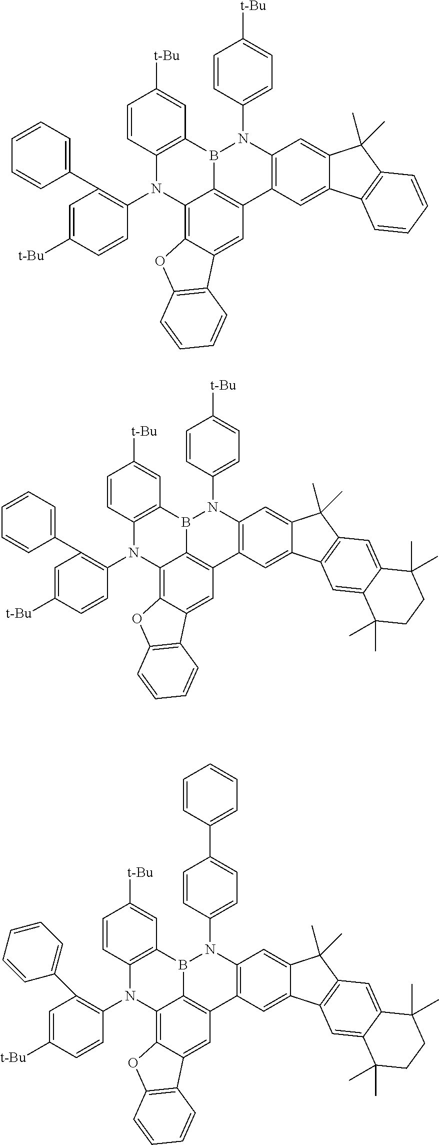 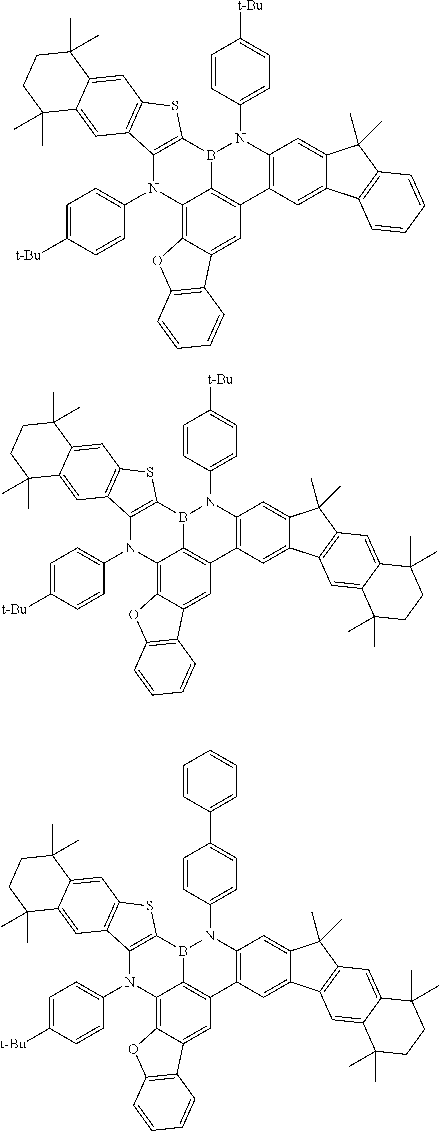 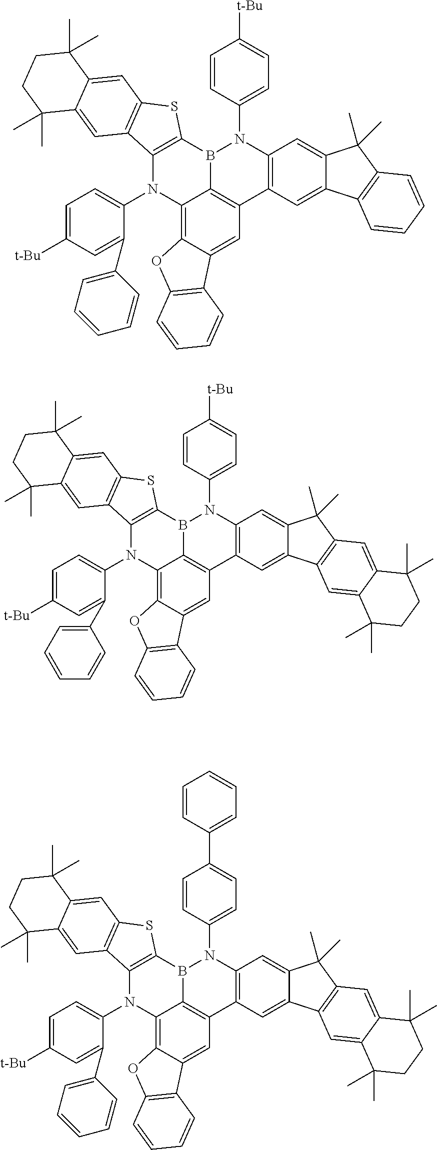 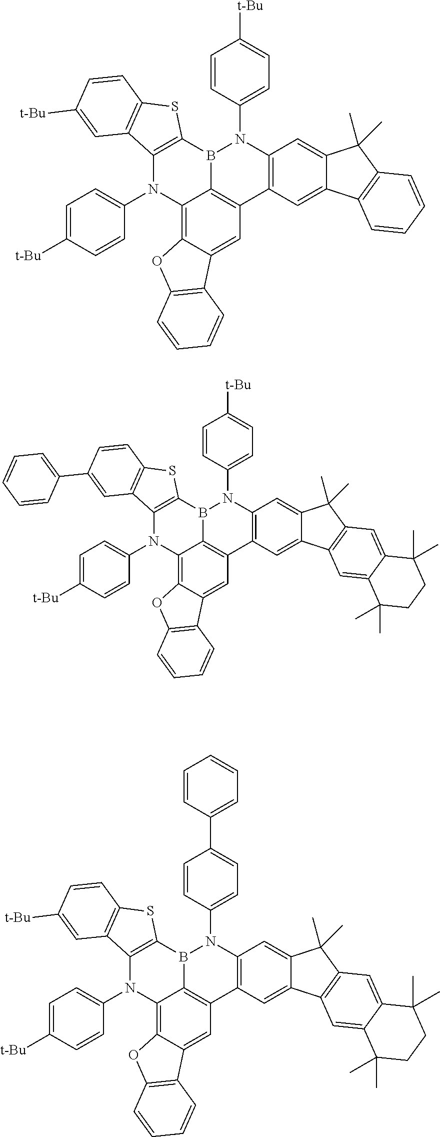 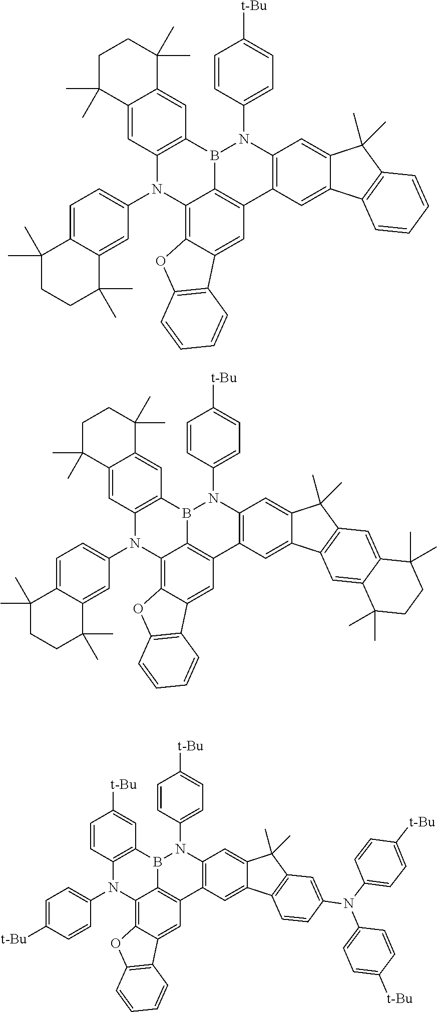 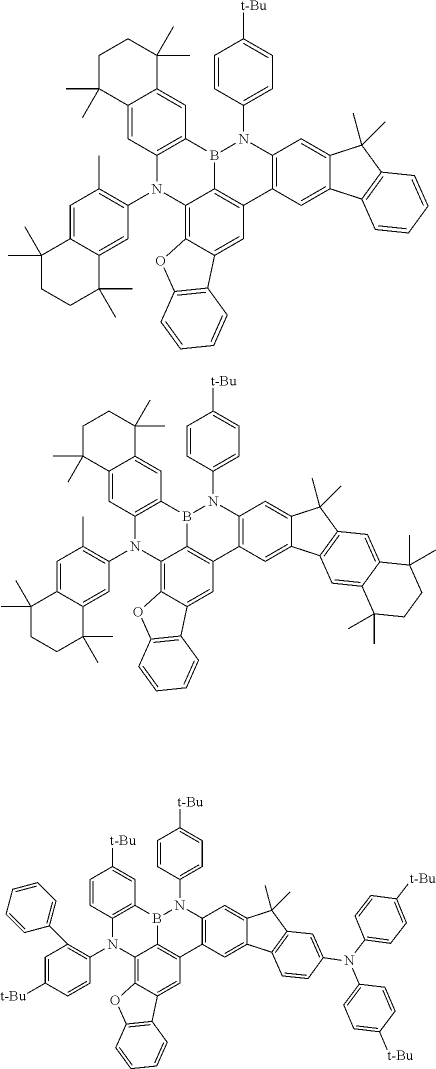 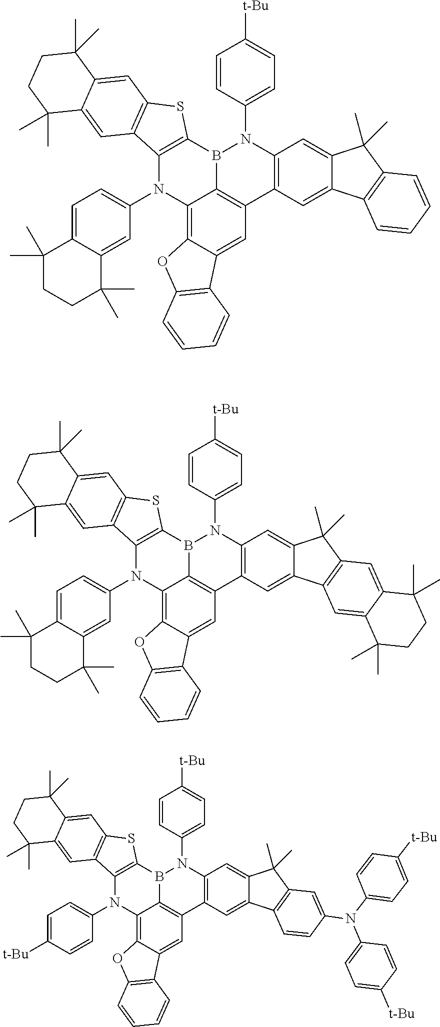 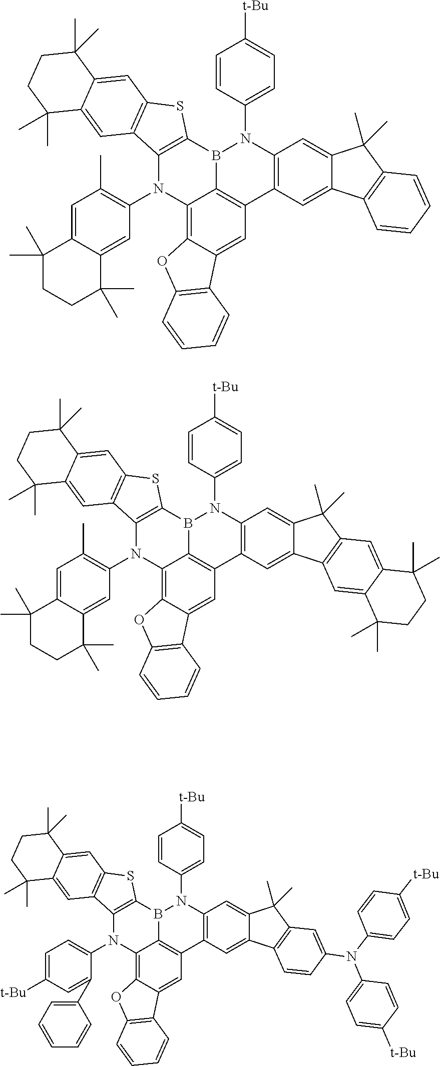 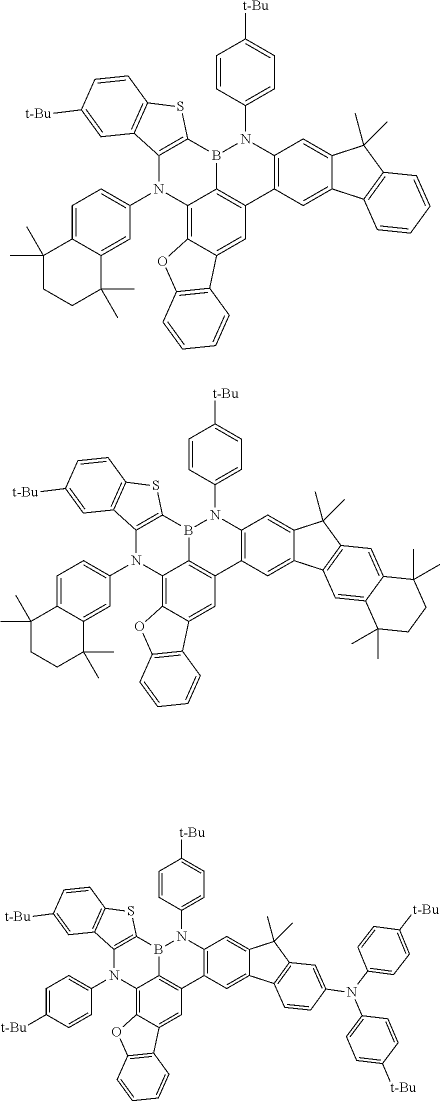 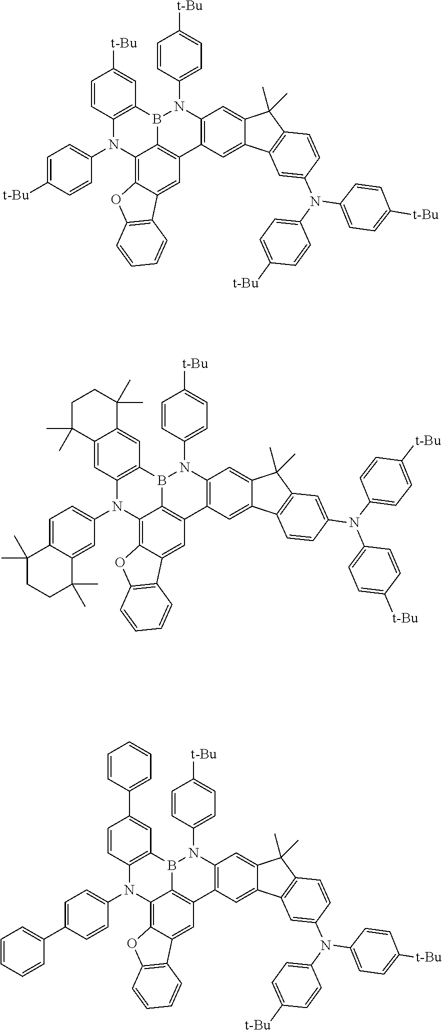 [SMILES: CC(C)(C)c1ccc(N2B3c4cc(C(C)(C)C)ccc4N(c4ccc(C(C)(C)C)cc4)c4c3c(cc3c4oc4ccccc43)-c3cc4c(cc32)C(C)(C)c2ccc(N(c3ccc(C(C)(C)C)cc3)c3ccc(C(C)(C)C)cc3)cc2-4)cc1 ; CC(C)(C)c1ccc(N2B3c4cc5c(cc4N(c4ccc6c(c4)C(C)(C)CCC6(C)C)c4c3c(cc3c4oc4ccccc43)-c3cc4c(cc32)C(C)(C)c2cc(N(c3ccc(C(C)(C)C)cc3)c3ccc(C(C)(C)C)cc3)ccc2-4)C(C)(C)CCC5(C)C)cc1 ; CC(C)(C)c1ccc(N2B3c4cc(-c5ccccc5)ccc4N(c4ccc(-c5ccccc5)cc4)c4c3c(cc3c4oc4ccccc43)-c3cc4c(cc32)C(C)(C)c2ccc(N(c3ccc(C(C)(C)C)cc3)c3ccc(C(C)(C)C)cc3)cc2-4)cc1] 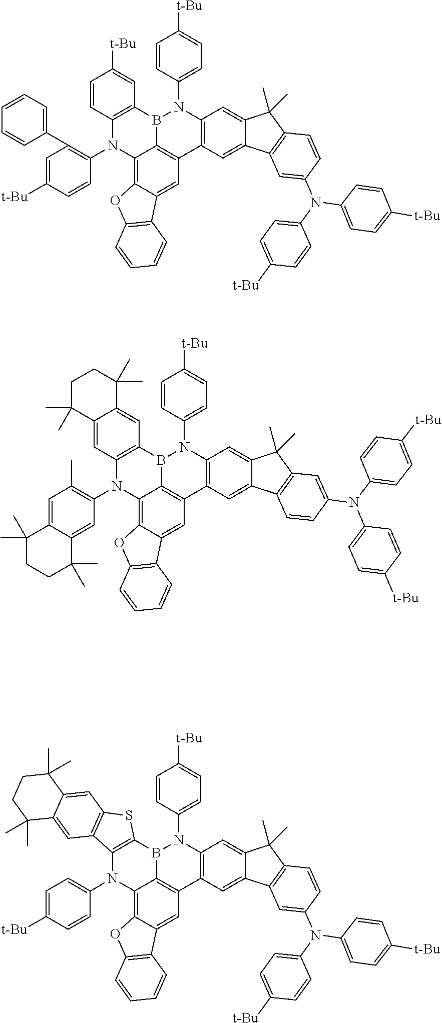 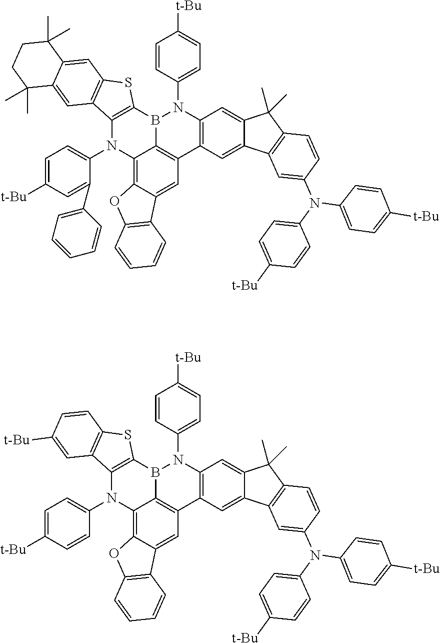 [SMILES: CC(C)(C)c1ccc(N2B3c4sc5cc6c(cc5c4N(c4ccc(C(C)(C)C)cc4-c4ccccc4)c4c3c(cc3c4oc4ccccc43)-c3cc4c(cc32)C(C)(C)c2ccc(N(c3ccc(C(C)(C)C)cc3)c3ccc(C(C)(C)C)cc3)cc2-4)C(C)(C)CCC6(C)C)cc1 ; CC(C)(C)c1ccc(N2B3c4sc5ccc(C(C)(C)C)cc5c4N(c4ccc(C(C)(C)C)cc4)c4c3c(cc3c4oc4ccccc43)-c3cc4c(cc32)C(C)(C)c2ccc(N(c3ccc(C(C)(C)C)cc3)c3ccc(C(C)(C)C)cc3)cc2-4)cc1] 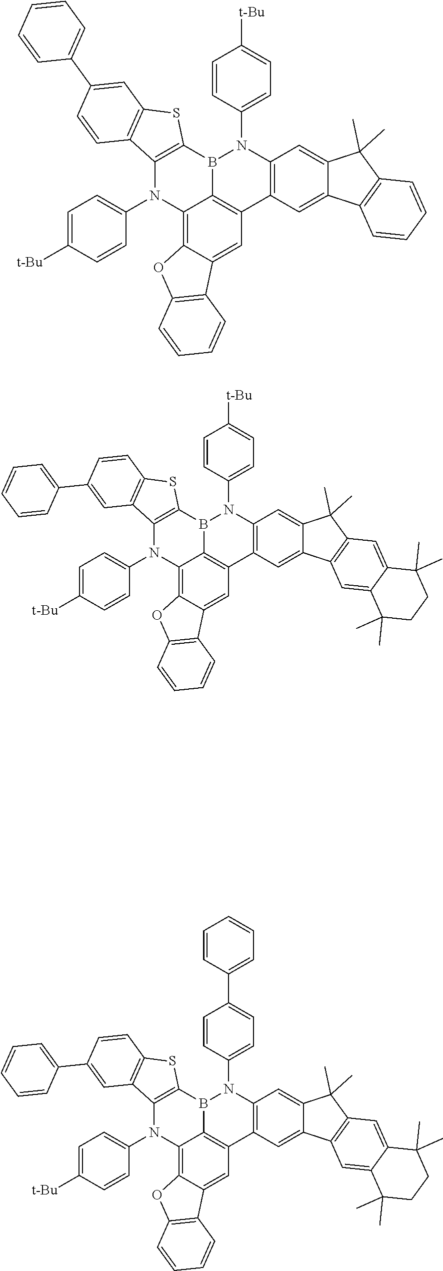 [SMILES: CC(C)(C)c1ccc(N2B3c4sc5cc(-c6ccccc6)ccc5c4N(c4ccc(C(C)(C)C)cc4)c4c3c(cc3c4oc4ccccc43)-c3cc4c(cc32)C(C)(C)c2ccccc2-4)cc1 ; CC(C)(C)c1ccc(N2B3c4sc5ccc(-c6ccccc6)cc5c4N(c4ccc(C(C)(C)C)cc4)c4c3c(cc3c4oc4ccccc43)-c3cc4c(cc32)C(C)(C)c2cc3c(cc2-4)C(C)(C)CCC3(C)C)cc1 ; CC(C)(C)c1ccc(N2c3c(sc4ccc(-c5ccccc5)cc34)B3c4c(cc5c(oc6ccccc65)c42)-c2cc4c(cc2N3c2ccc(-c3ccccc3)cc2)C(C)(C)c2cc3c(cc2-4)C(C)(C)CCC3(C)C)cc1] 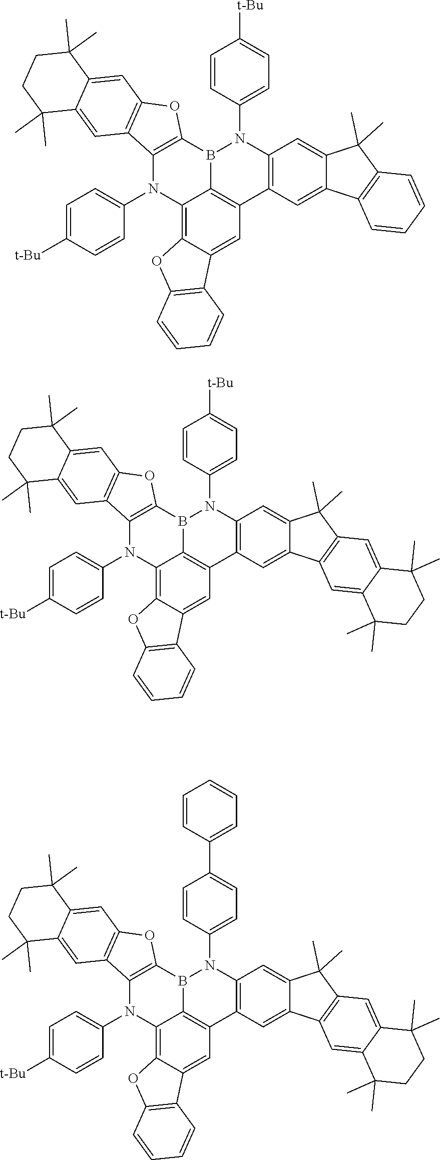 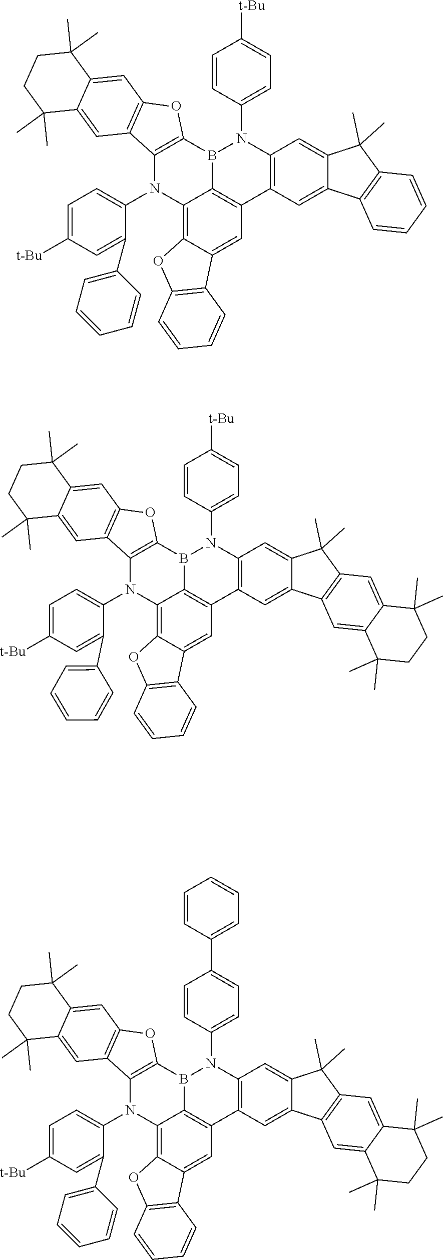 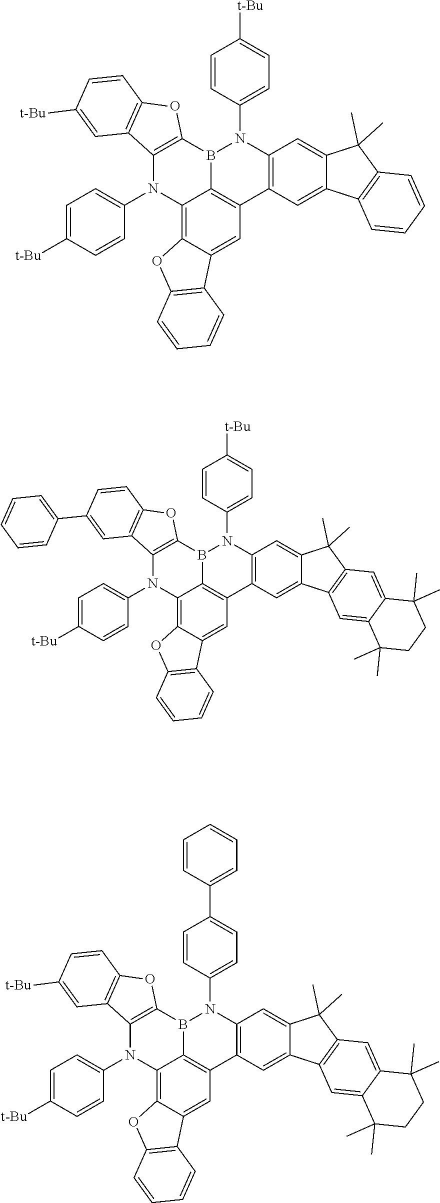 [SMILES: CC(C)(C)c1ccc(N2B3c4oc5ccc(C(C)(C)C)cc5c4N(c4ccc(C(C)(C)C)cc4)c4c3c(cc3c4oc4ccccc43)-c3cc4c(cc32)C(C)(C)c2ccccc2-4)cc1 ; CC(C)(C)c1ccc(N2B3c4oc5ccc(-c6ccccc6)cc5c4N(c4ccc(C(C)(C)C)cc4)c4c3c(cc3c4oc4ccccc43)-c3cc4c(cc32)C(C)(C)c2cc3c(cc2-4)C(C)(C)CCC3(C)C)cc1 ; CC(C)(C)c1ccc(N2c3c(oc4ccc(C(C)(C)C)cc34)B3c4c(cc5c(oc6ccccc65)c42)-c2cc4c(cc2N3c2ccc(-c3ccccc3)cc2)C(C)(C)c2cc3c(cc2-4)C(C)(C)CCC3(C)C)cc1] 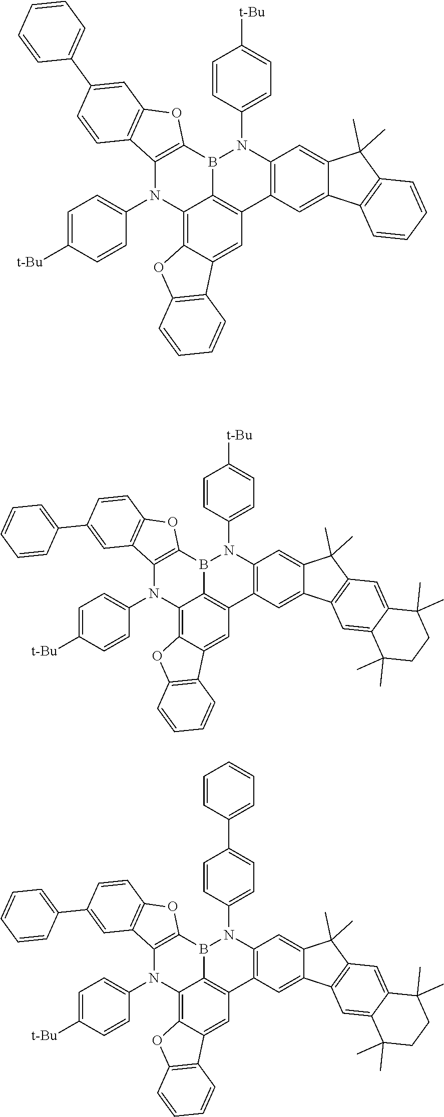 [SMILES: CC(C)(C)c1ccc(N2B3c4oc5cc(-c6ccccc6)ccc5c4N(c4ccc(C(C)(C)C)cc4)c4c3c(cc3c4oc4ccccc43)-c3cc4c(cc32)C(C)(C)c2ccccc2-4)cc1 ; CC(C)(C)c1ccc(N2B3c4oc5ccc(-c6ccccc6)cc5c4N(c4ccc(C(C)(C)C)cc4)c4c3c(cc3c4oc4ccccc43)-c3cc4c(cc32)C(C)(C)c2cc3c(cc2-4)C(C)(C)CCC3(C)C)cc1 ; CC(C)(C)c1ccc(N2c3c(oc4ccc(-c5ccccc5)cc34)B3c4c(cc5c(oc6ccccc65)c42)-c2cc4c(cc2N3c2ccc(-c3ccccc3)cc2)C(C)(C)c2cc3c(cc2-4)C(C)(C)CCC3(C)C)cc1] 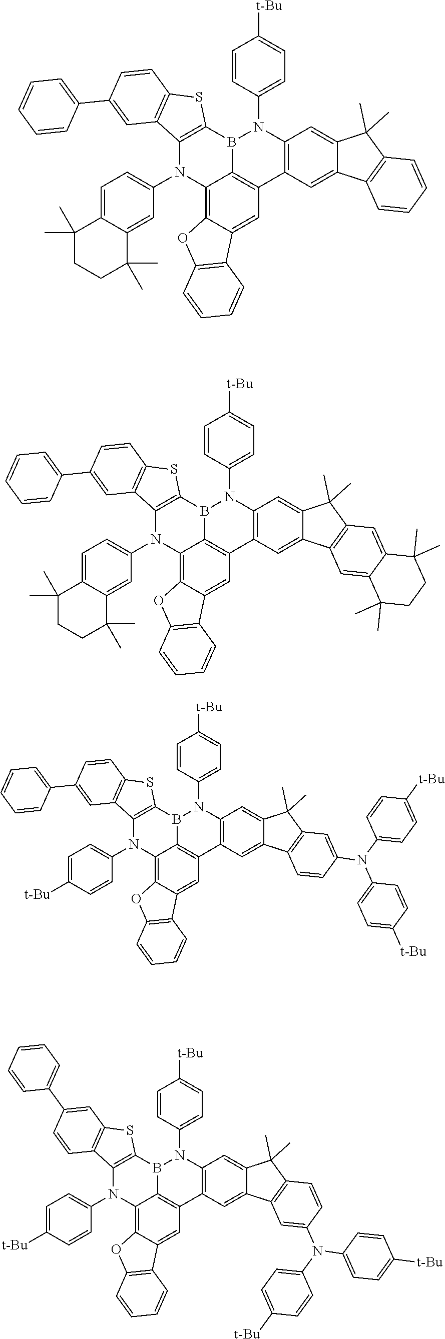 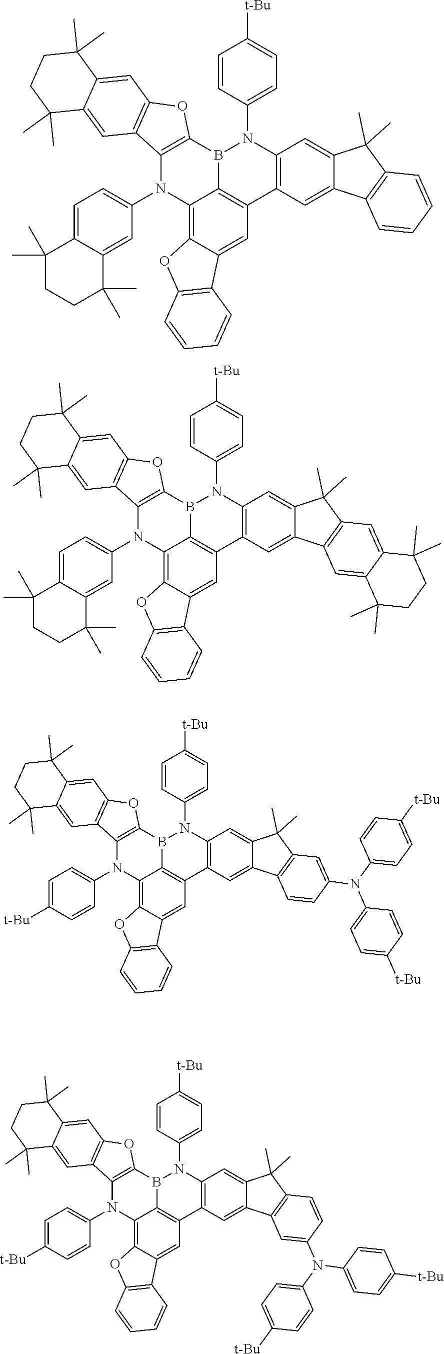 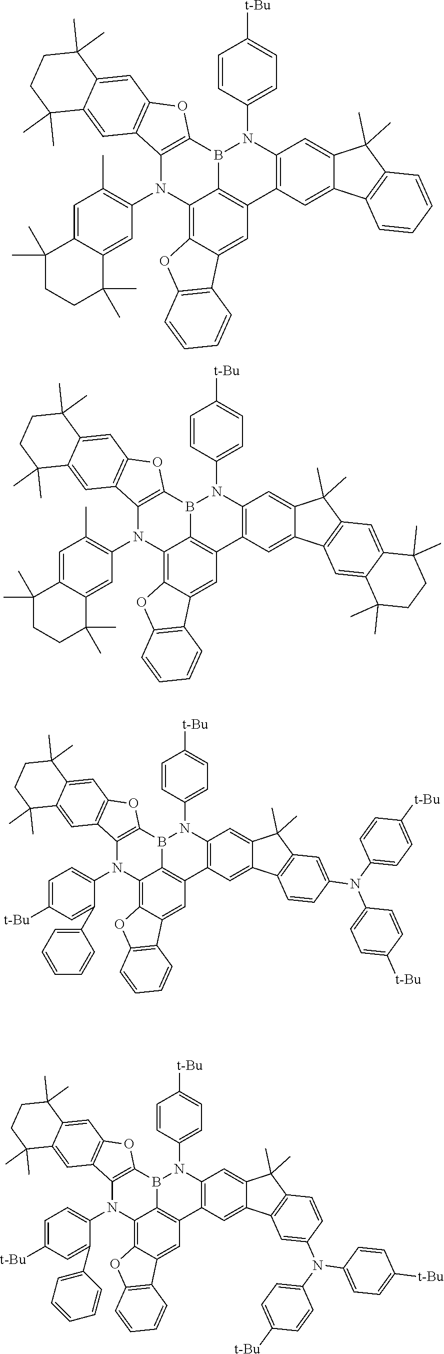 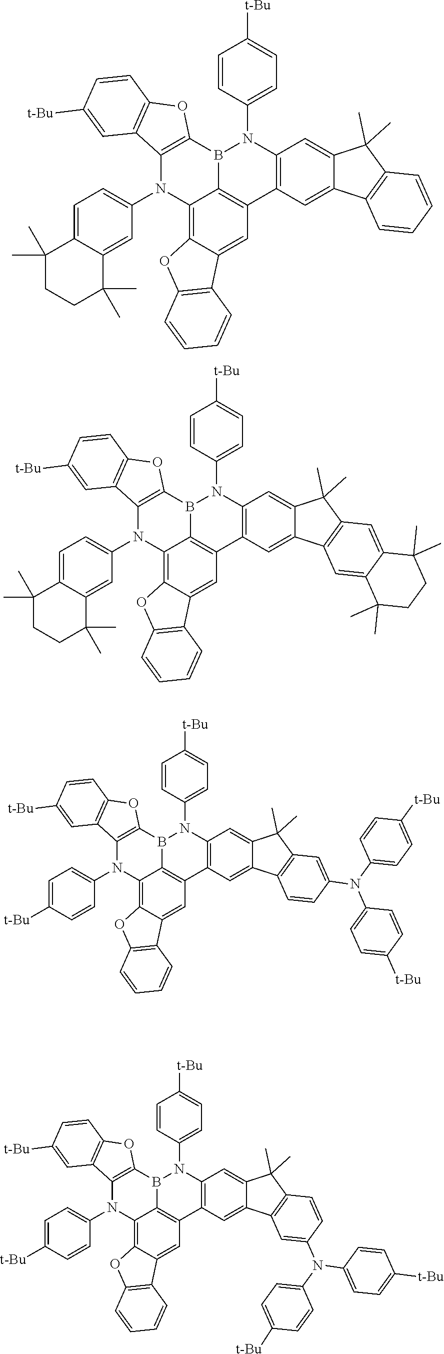 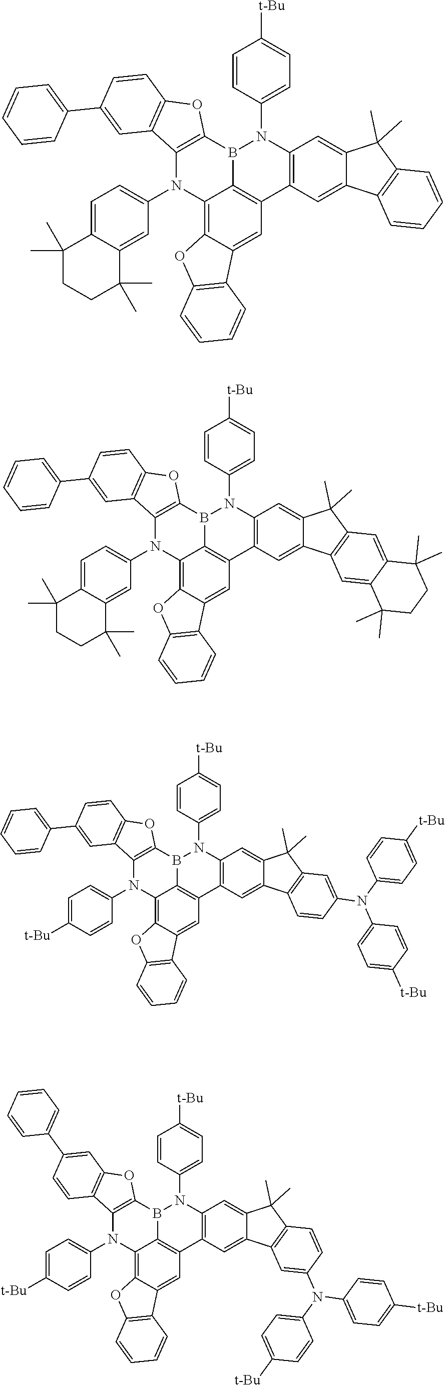 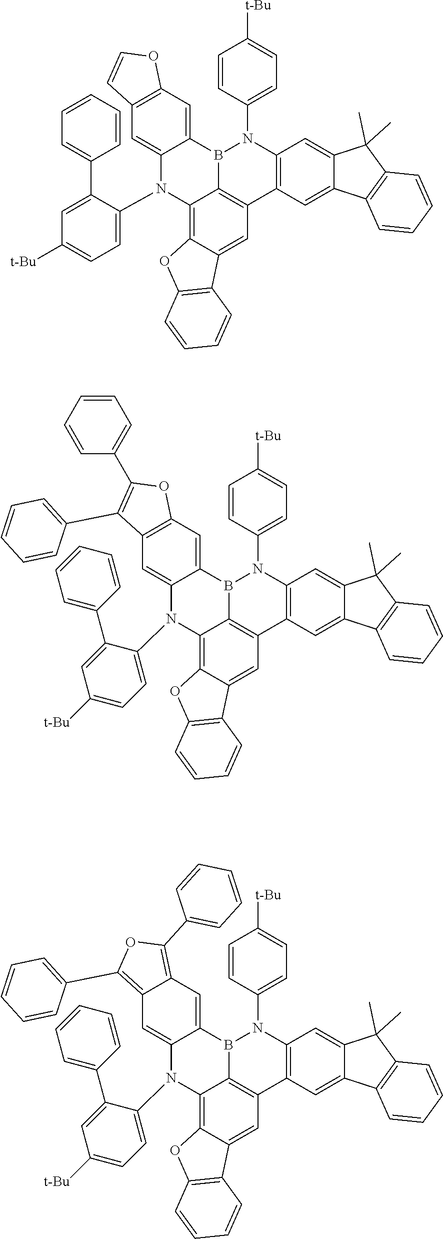 [SMILES: CC(C)(C)c1ccc(N2B3c4cc5occc5cc4N(c4ccc(C(C)(C)C)cc4-c4ccccc4)c4c3c(cc3c4oc4ccccc43)-c3cc4c(cc32)C(C)(C)c2ccccc2-4)cc1 ; CC(C)(C)c1ccc(N2B3c4cc5oc(-c6ccccc6)c(-c6ccccc6)c5cc4N(c4ccc(C(C)(C)C)cc4-c4ccccc4)c4c3c(cc3c4oc4ccccc43)-c3cc4c(cc32)C(C)(C)c2ccccc2-4)cc1 ; CC(C)(C)c1ccc(N2B3c4cc5c(-c6ccccc6)oc(-c6ccccc6)c5cc4N(c4ccc(C(C)(C)C)cc4-c4ccccc4)c4c3c(cc3c4oc4ccccc43)-c3cc4c(cc32)C(C)(C)c2ccccc2-4)cc1] 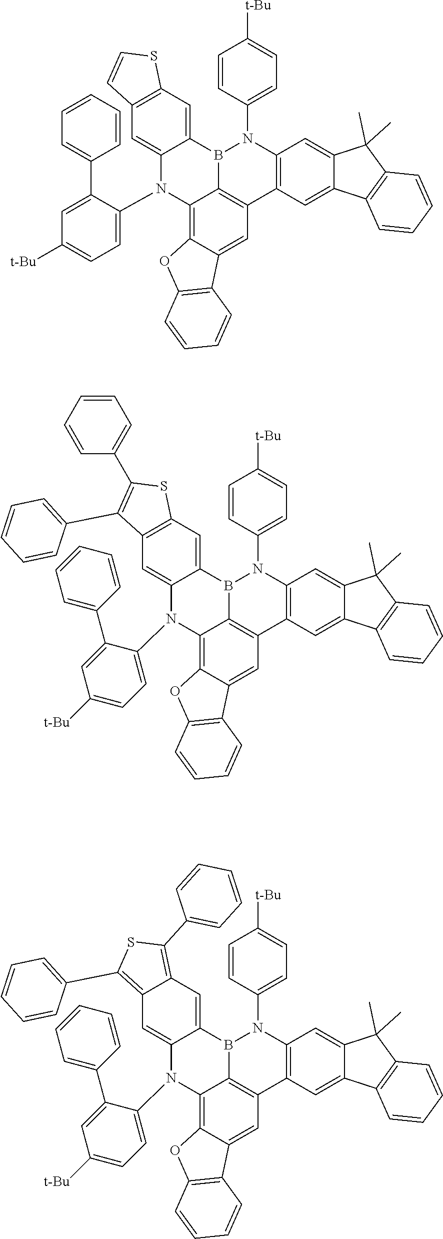 [SMILES: CC(C)(C)c1ccc(N2B3c4cc5sccc5cc4N(c4ccc(C(C)(C)C)cc4-c4ccccc4)c4c3c(cc3c4oc4ccccc43)-c3cc4c(cc32)C(C)(C)c2ccccc2-4)cc1 ; CC(C)(C)c1ccc(N2B3c4cc5sc(-c6ccccc6)c(-c6ccccc6)c5cc4N(c4ccc(C(C)(C)C)cc4-c4ccccc4)c4c3c(cc3c4oc4ccccc43)-c3cc4c(cc32)C(C)(C)c2ccccc2-4)cc1 ; CC(C)(C)c1ccc(N2B3c4cc5c(-c6ccccc6)sc(-c6ccccc6)c5cc4N(c4ccc(C(C)(C)C)cc4-c4ccccc4)c4c3c(cc3c4oc4ccccc43)-c3cc4c(cc32)C(C)(C)c2ccccc2-4)cc1] 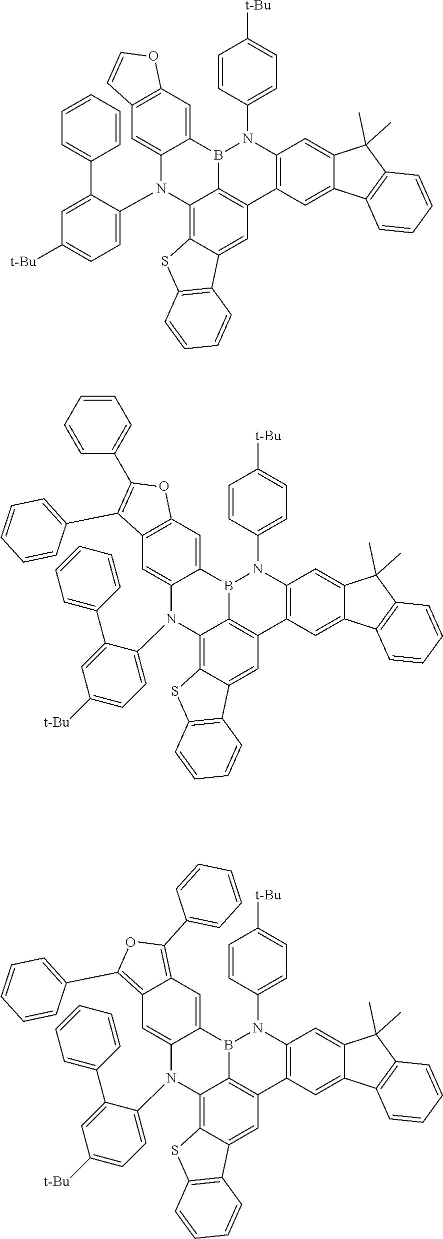 [SMILES: CC(C)(C)c1ccc(N2B3c4cc5occc5cc4N(c4ccc(C(C)(C)C)cc4-c4ccccc4)c4c3c(cc3c4sc4ccccc43)-c3cc4c(cc32)C(C)(C)c2ccccc2-4)cc1 ; CC(C)(C)c1ccc(N2B3c4cc5oc(-c6ccccc6)c(-c6ccccc6)c5cc4N(c4ccc(C(C)(C)C)cc4-c4ccccc4)c4c3c(cc3c4sc4ccccc43)-c3cc4c(cc32)C(C)(C)c2ccccc2-4)cc1 ; CC(C)(C)c1ccc(N2B3c4cc5c(-c6ccccc6)oc(-c6ccccc6)c5cc4N(c4ccc(C(C)(C)C)cc4-c4ccccc4)c4c3c(cc3c4sc4ccccc43)-c3cc4c(cc32)C(C)(C)c2ccccc2-4)cc1] 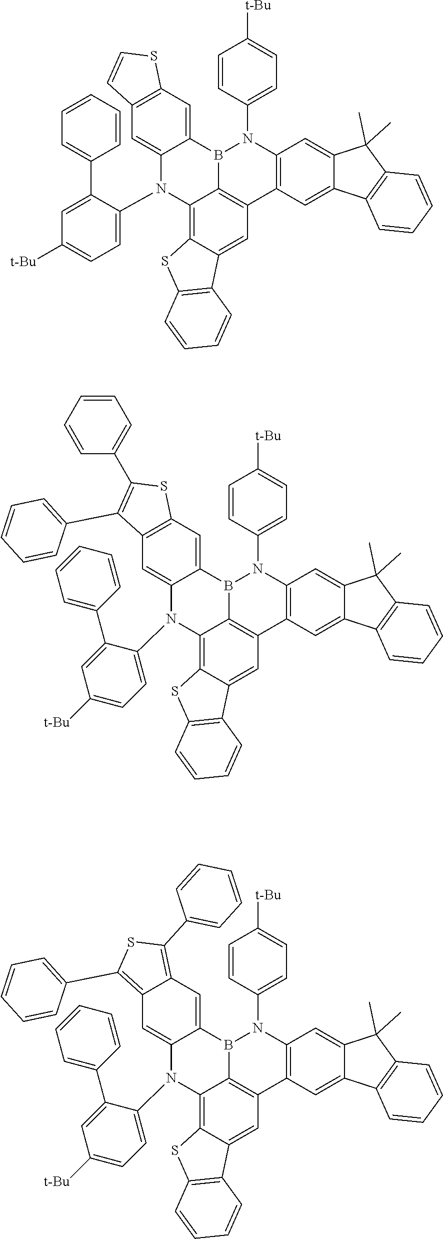 [SMILES: CC(C)(C)c1ccc(N2B3c4cc5sccc5cc4N(c4ccc(C(C)(C)C)cc4-c4ccccc4)c4c3c(cc3c4sc4ccccc43)-c3cc4c(cc32)C(C)(C)c2ccccc2-4)cc1 ; CC(C)(C)c1ccc(N2B3c4cc5sc(-c6ccccc6)c(-c6ccccc6)c5cc4N(c4ccc(C(C)(C)C)cc4-c4ccccc4)c4c3c(cc3c4sc4ccccc43)-c3cc4c(cc32)C(C)(C)c2ccccc2-4)cc1 ; CC(C)(C)c1ccc(N2B3c4cc5c(-c6ccccc6)sc(-c6ccccc6)c5cc4N(c4ccc(C(C)(C)C)cc4-c4ccccc4)c4c3c(cc3c4sc4ccccc43)-c3cc4c(cc32)C(C)(C)c2ccccc2-4)cc1] 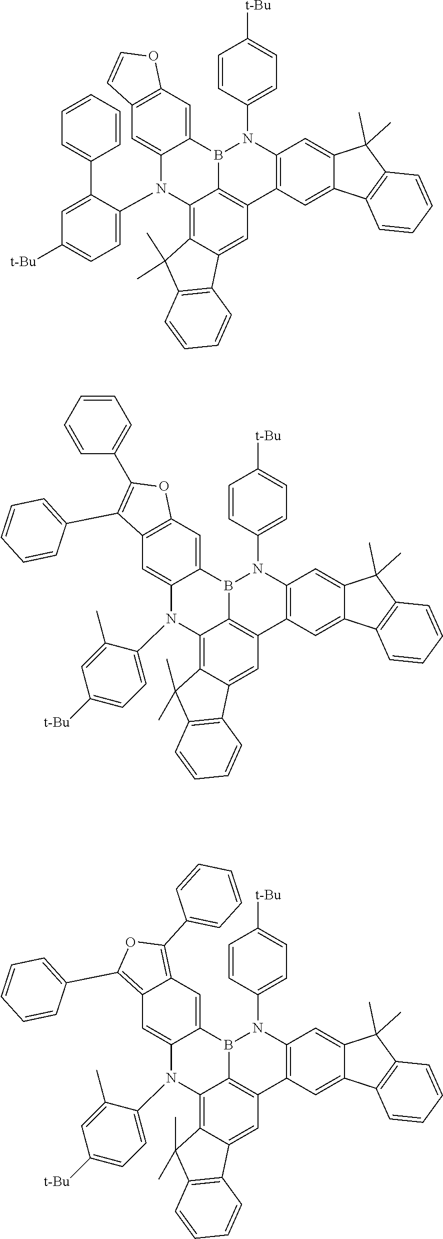 [SMILES: CC(C)(C)c1ccc(N2B3c4cc5occc5cc4N(c4ccc(C(C)(C)C)cc4-c4ccccc4)c4c3c(cc3c4C(C)(C)c4ccccc4-3)-c3cc4c(cc32)C(C)(C)c2ccccc2-4)cc1 ; Cc1cc(C(C)(C)C)ccc1N1c2cc3c(-c4ccccc4)c(-c4ccccc4)oc3cc2B2c3c(cc4c(c31)C(C)(C)c1ccccc1-4)-c1cc3c(cc1N2c1ccc(C(C)(C)C)cc1)C(C)(C)c1ccccc1-3 ; Cc1cc(C(C)(C)C)ccc1N1c2cc3c(-c4ccccc4)oc(-c4ccccc4)c3cc2B2c3c(cc4c(c31)C(C)(C)c1ccccc1-4)-c1cc3c(cc1N2c1ccc(C(C)(C)C)cc1)C(C)(C)c1ccccc1-3] 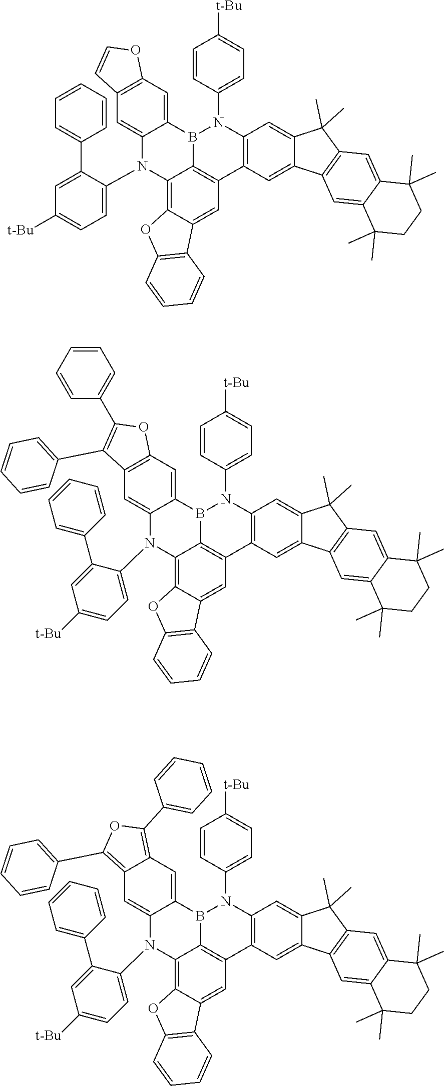 [SMILES: CC(C)(C)c1ccc(N2B3c4cc5occc5cc4N(c4ccc(C(C)(C)C)cc4-c4ccccc4)c4c3c(cc3c4oc4ccccc43)-c3cc4c(cc32)C(C)(C)c2cc3c(cc2-4)C(C)(C)CCC3(C)C)cc1 ; CC(C)(C)c1ccc(N2B3c4cc5oc(-c6ccccc6)c(-c6ccccc6)c5cc4N(c4ccc(C(C)(C)C)cc4-c4ccccc4)c4c3c(cc3c4oc4ccccc43)-c3cc4c(cc32)C(C)(C)c2cc3c(cc2-4)C(C)(C)CCC3(C)C)cc1 ; CC(C)(C)c1ccc(N2B3c4cc5c(-c6ccccc6)oc(-c6ccccc6)c5cc4N(c4ccc(C(C)(C)C)cc4-c4ccccc4)c4c3c(cc3c4oc4ccccc43)-c3cc4c(cc32)C(C)(C)c2cc3c(cc2-4)C(C)(C)CCC3(C)C)cc1] 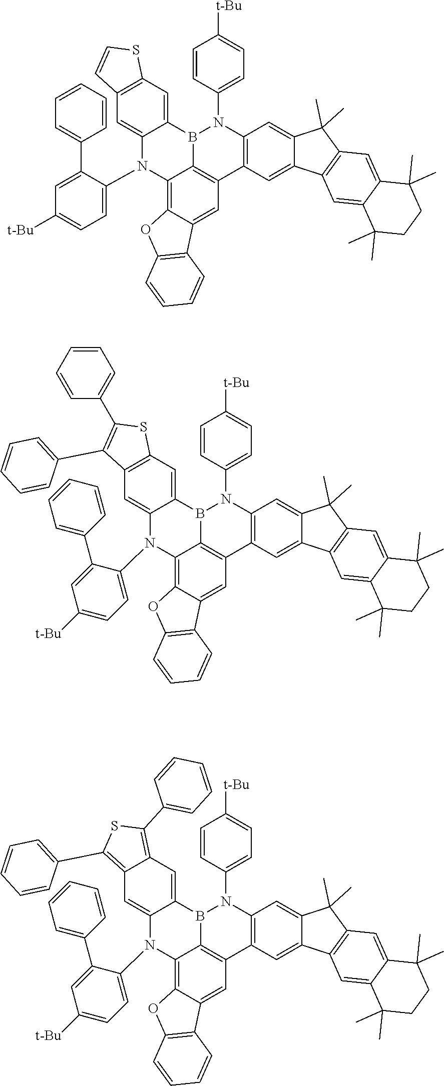 [SMILES: CC(C)(C)c1ccc(N2B3c4cc5sccc5cc4N(c4ccc(C(C)(C)C)cc4-c4ccccc4)c4c3c(cc3c4oc4ccccc43)-c3cc4c(cc32)C(C)(C)c2cc3c(cc2-4)C(C)(C)CCC3(C)C)cc1 ; CC(C)(C)c1ccc(N2B3c4cc5sc(-c6ccccc6)c(-c6ccccc6)c5cc4N(c4ccc(C(C)(C)C)cc4-c4ccccc4)c4c3c(cc3c4oc4ccccc43)-c3cc4c(cc32)C(C)(C)c2cc3c(cc2-4)C(C)(C)CCC3(C)C)cc1 ; CC(C)(C)c1ccc(N2B3c4cc5c(-c6ccccc6)sc(-c6ccccc6)c5cc4N(c4ccc(C(C)(C)C)cc4-c4ccccc4)c4c3c(cc3c4oc4ccccc43)-c3cc4c(cc32)C(C)(C)c2cc3c(cc2-4)C(C)(C)CCC3(C)C)cc1] 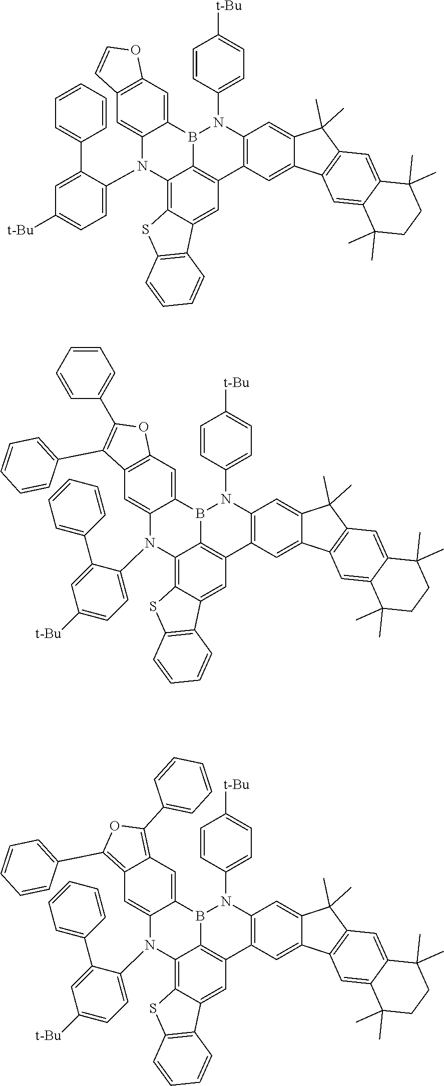 [SMILES: CC(C)(C)c1ccc(N2B3c4cc5occc5cc4N(c4ccc(C(C)(C)C)cc4-c4ccccc4)c4c3c(cc3c4sc4ccccc43)-c3cc4c(cc32)C(C)(C)c2cc3c(cc2-4)C(C)(C)CCC3(C)C)cc1 ; CC(C)(C)c1ccc(N2B3c4cc5oc(-c6ccccc6)c(-c6ccccc6)c5cc4N(c4ccc(C(C)(C)C)cc4-c4ccccc4)c4c3c(cc3c4sc4ccccc43)-c3cc4c(cc32)C(C)(C)c2cc3c(cc2-4)C(C)(C)CCC3(C)C)cc1 ; CC(C)(C)c1ccc(N2B3c4cc5c(-c6ccccc6)oc(-c6ccccc6)c5cc4N(c4ccc(C(C)(C)C)cc4-c4ccccc4)c4c3c(cc3c4sc4ccccc43)-c3cc4c(cc32)C(C)(C)c2cc3c(cc2-4)C(C)(C)CCC3(C)C)cc1] 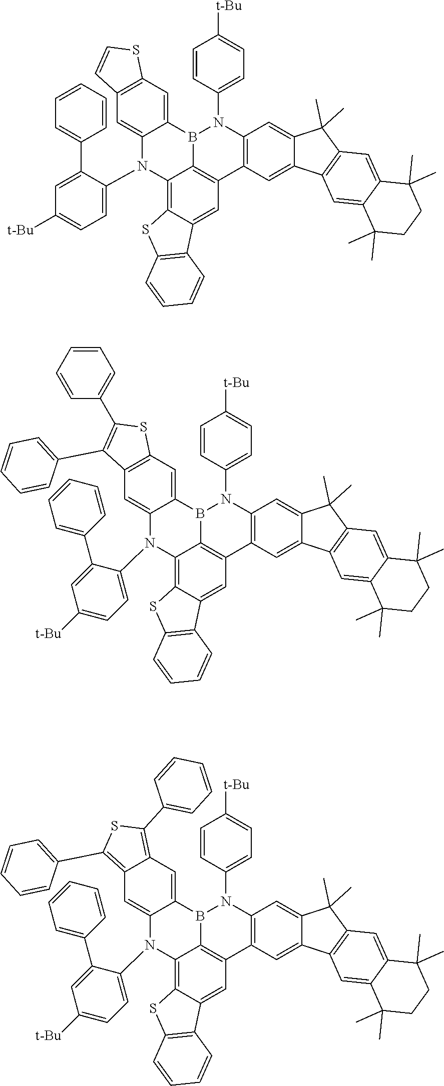 [SMILES: CC(C)(C)c1ccc(N2B3c4cc5sccc5cc4N(c4ccc(C(C)(C)C)cc4-c4ccccc4)c4c3c(cc3c4sc4ccccc43)-c3cc4c(cc32)C(C)(C)c2cc3c(cc2-4)C(C)(C)CCC3(C)C)cc1 ; CC(C)(C)c1ccc(N2B3c4cc5sc(-c6ccccc6)c(-c6ccccc6)c5cc4N(c4ccc(C(C)(C)C)cc4-c4ccccc4)c4c3c(cc3c4sc4ccccc43)-c3cc4c(cc32)C(C)(C)c2cc3c(cc2-4)C(C)(C)CCC3(C)C)cc1 ; CC(C)(C)c1ccc(N2B3c4cc5c(-c6ccccc6)sc(-c6ccccc6)c5cc4N(c4ccc(C(C)(C)C)cc4-c4ccccc4)c4c3c(cc3c4sc4ccccc43)-c3cc4c(cc32)C(C)(C)c2cc3c(cc2-4)C(C)(C)CCC3(C)C)cc1] 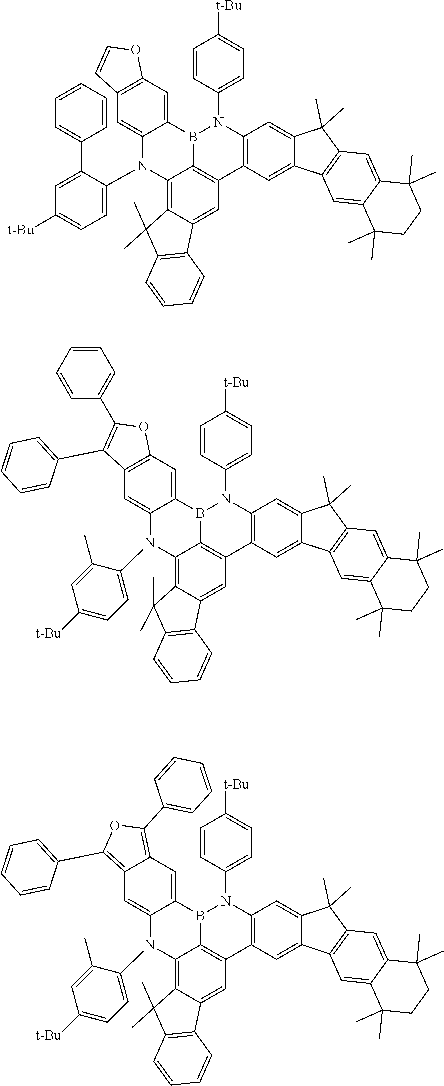 [SMILES: CC(C)(C)c1ccc(N2B3c4cc5occc5cc4N(c4ccc(C(C)(C)C)cc4-c4ccccc4)c4c3c(cc3c4C(C)(C)c4ccccc4-3)-c3cc4c(cc32)C(C)(C)c2cc3c(cc2-4)C(C)(C)CCC3(C)C)cc1 ; Cc1cc(C(C)(C)C)ccc1N1c2cc3c(-c4ccccc4)c(-c4ccccc4)oc3cc2B2c3c(cc4c(c31)C(C)(C)c1ccccc1-4)-c1cc3c(cc1N2c1ccc(C(C)(C)C)cc1)C(C)(C)c1cc2c(cc1-3)C(C)(C)CCC2(C)C ; Cc1cc(C(C)(C)C)ccc1N1c2cc3c(-c4ccccc4)oc(-c4ccccc4)c3cc2B2c3c(cc4c(c31)C(C)(C)c1ccccc1-4)-c1cc3c(cc1N2c1ccc(C(C)(C)C)cc1)C(C)(C)c1cc2c(cc1-3)C(C)(C)CCC2(C)C] 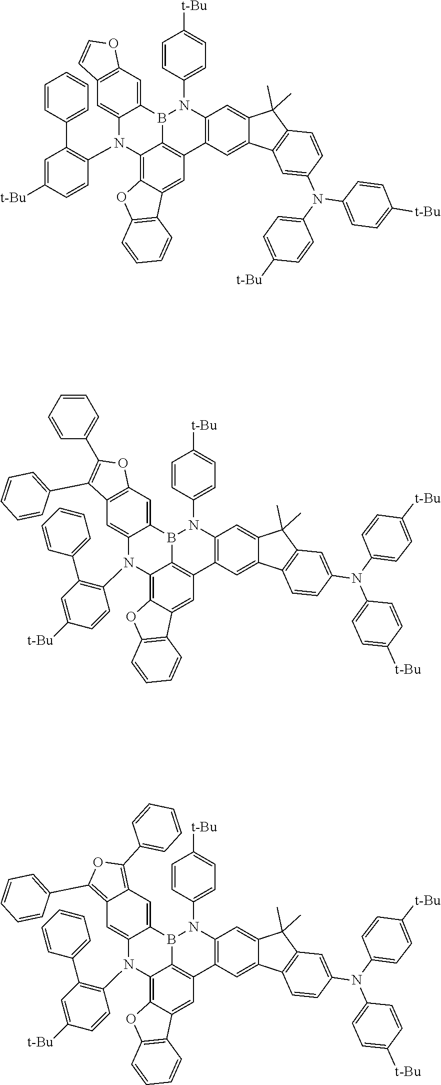 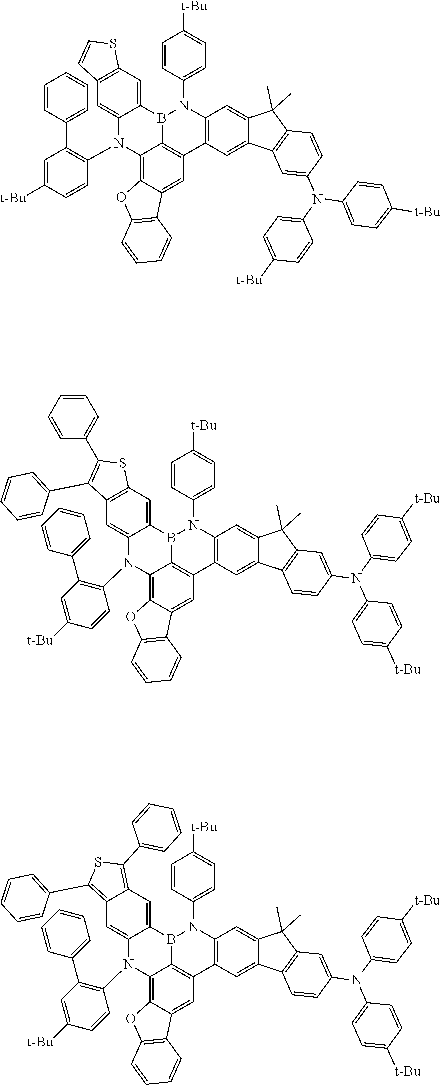 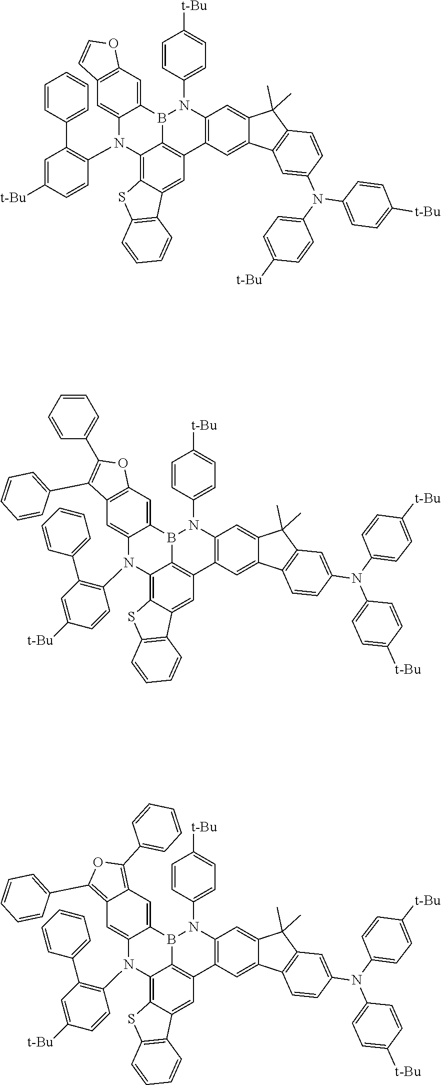 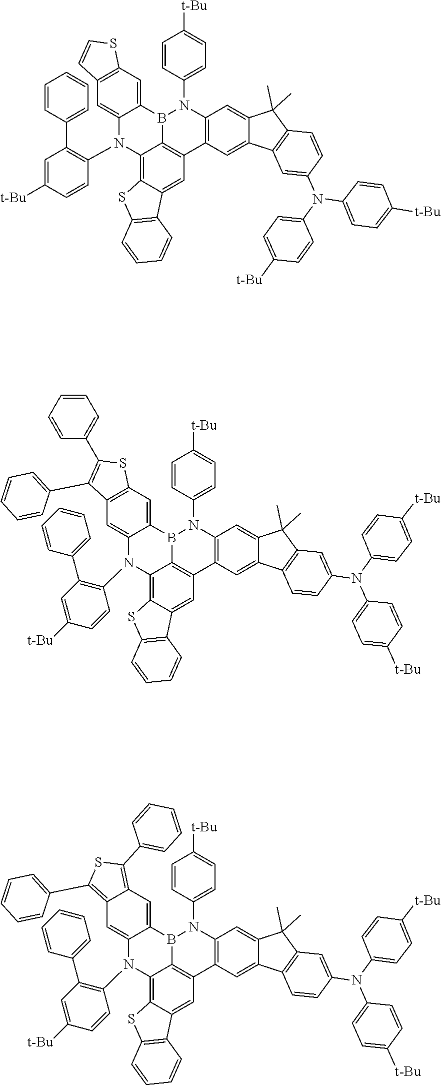 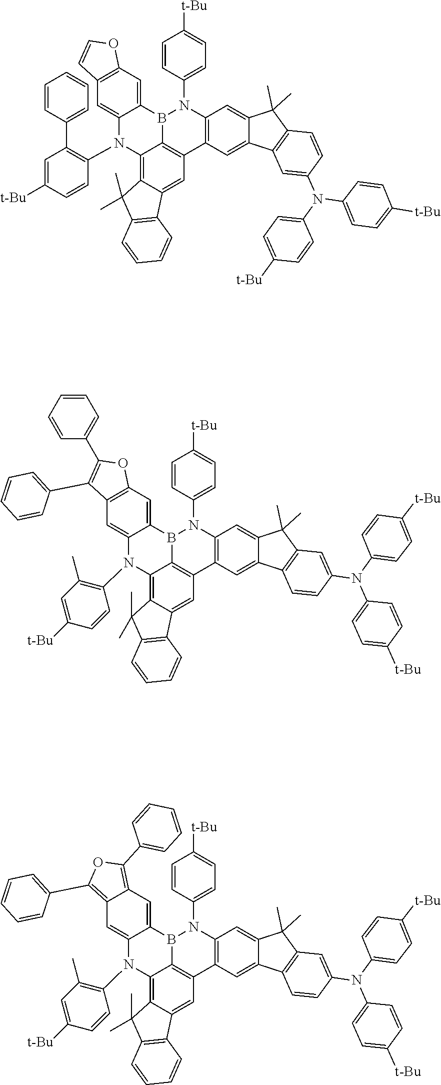 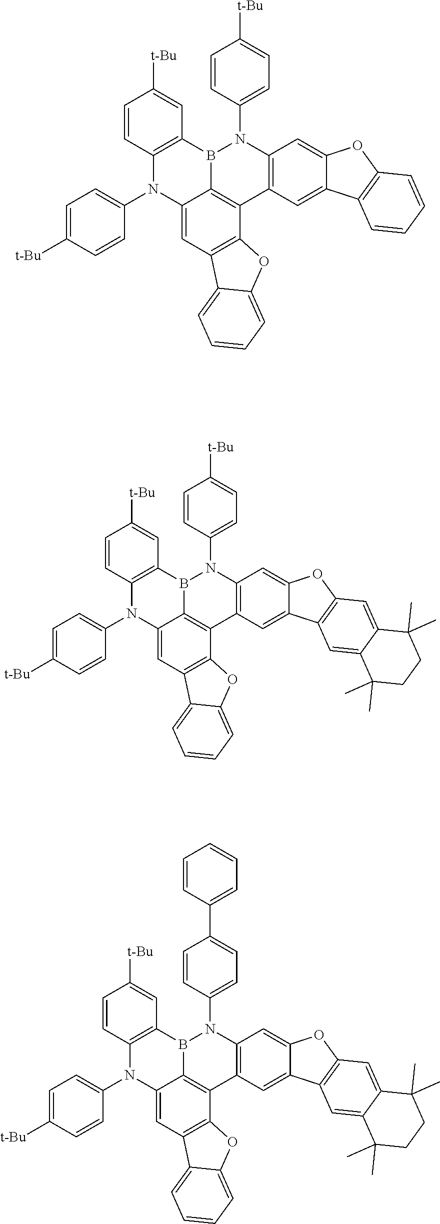 [SMILES: CC(C)(C)c1ccc(N2B3c4cc(C(C)(C)C)ccc4N(c4ccc(C(C)(C)C)cc4)c4cc5c(oc6ccccc65)c(c43)-c3cc4c(cc32)oc2ccccc24)cc1 ; CC(C)(C)c1ccc(N2B3c4cc(C(C)(C)C)ccc4N(c4ccc(C(C)(C)C)cc4)c4cc5c(oc6ccccc65)c(c43)-c3cc4c(cc32)oc2cc3c(cc24)C(C)(C)CCC3(C)C)cc1 ; CC(C)(C)c1ccc(N2c3ccc(C(C)(C)C)cc3B3c4c2cc2c(oc5ccccc52)c4-c2cc4c(cc2N3c2ccc(-c3ccccc3)cc2)oc2cc3c(cc24)C(C)(C)CCC3(C)C)cc1] 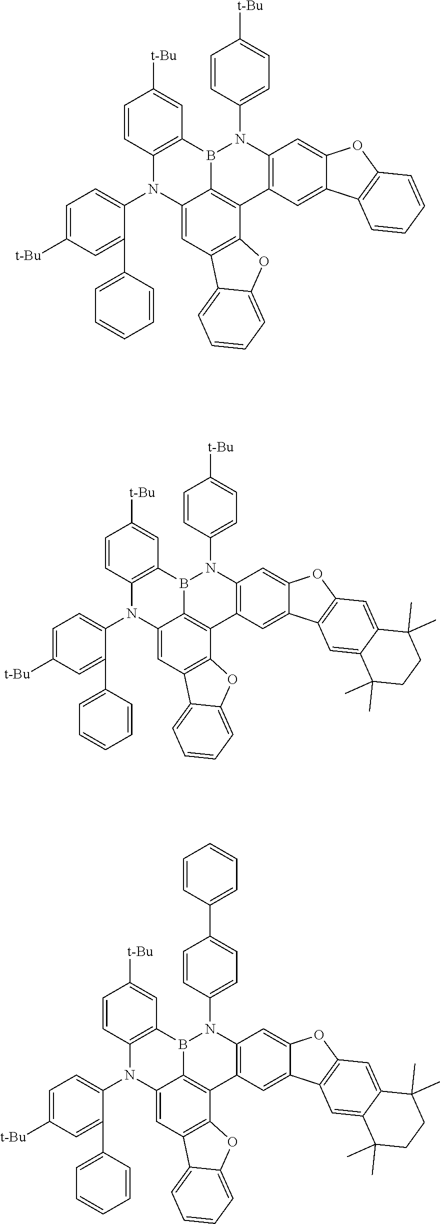 [SMILES: CC(C)(C)c1ccc(N2B3c4cc(C(C)(C)C)ccc4N(c4ccc(C(C)(C)C)cc4-c4ccccc4)c4cc5c(oc6ccccc65)c(c43)-c3cc4c(cc32)oc2ccccc24)cc1 ; CC(C)(C)c1ccc(N2B3c4cc(C(C)(C)C)ccc4N(c4ccc(C(C)(C)C)cc4-c4ccccc4)c4cc5c(oc6ccccc65)c(c43)-c3cc4c(cc32)oc2cc3c(cc24)C(C)(C)CCC3(C)C)cc1 ; CC(C)(C)c1ccc2c(c1)B1c3c(cc4c(oc5ccccc54)c3-c3cc4c(cc3N1c1ccc(-c3ccccc3)cc1)oc1cc3c(cc14)C(C)(C)CCC3(C)C)N2c1ccc(C(C)(C)C)cc1-c1ccccc1] 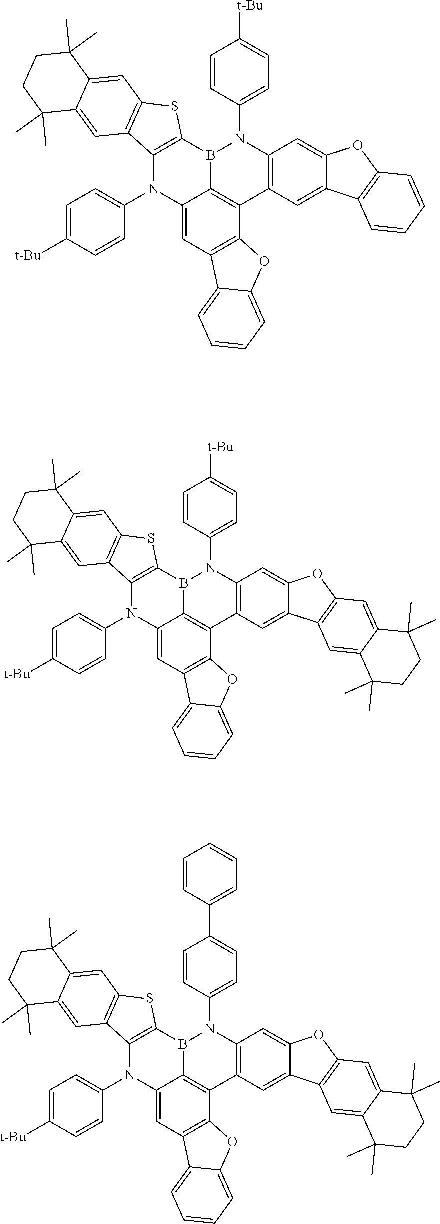 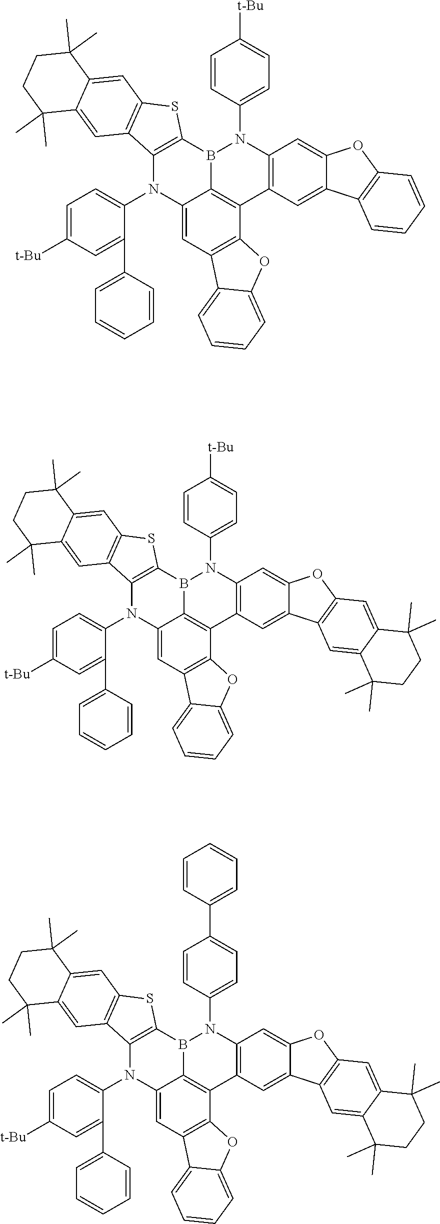 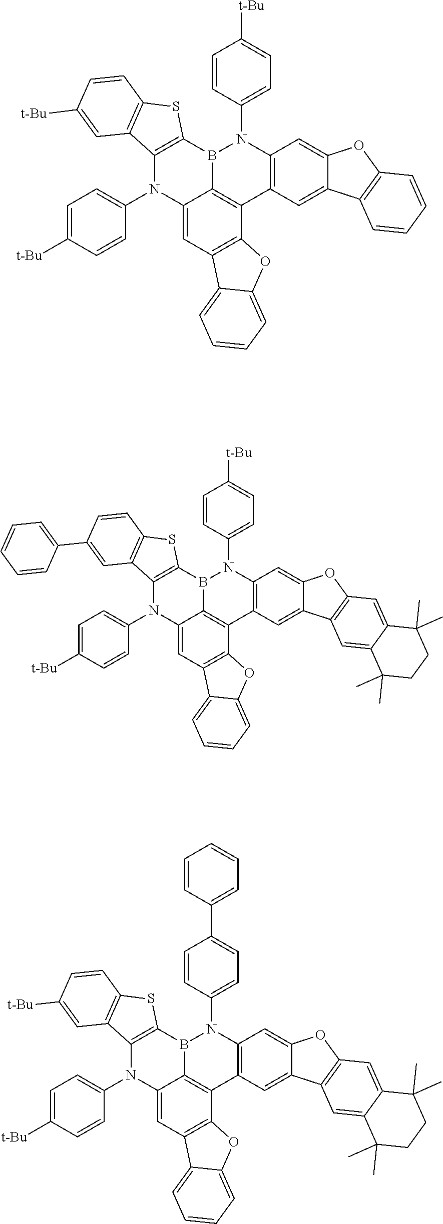 [SMILES: CC(C)(C)c1ccc(N2B3c4sc5ccc(C(C)(C)C)cc5c4N(c4ccc(C(C)(C)C)cc4)c4cc5c(oc6ccccc65)c(c43)-c3cc4c(cc32)oc2ccccc24)cc1 ; CC(C)(C)c1ccc(N2B3c4sc5ccc(-c6ccccc6)cc5c4N(c4ccc(C(C)(C)C)cc4)c4cc5c(oc6ccccc65)c(c43)-c3cc4c(cc32)oc2cc3c(cc24)C(C)(C)CCC3(C)C)cc1 ; CC(C)(C)c1ccc(N2c3cc4c(oc5ccccc54)c4c3B(c3sc5ccc(C(C)(C)C)cc5c32)N(c2ccc(-c3ccccc3)cc2)c2cc3oc5cc6c(cc5c3cc2-4)C(C)(C)CCC6(C)C)cc1] 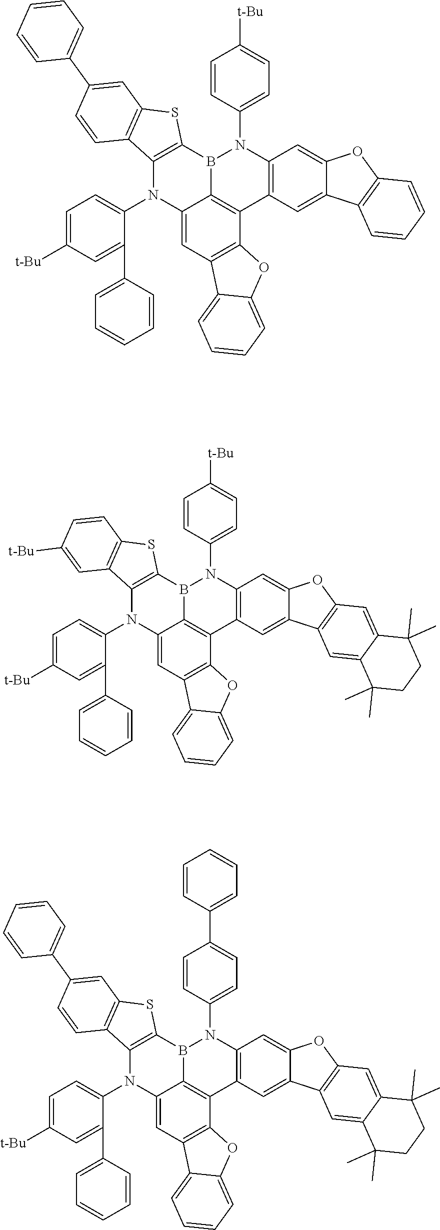 [SMILES: CC(C)(C)c1ccc(N2B3c4sc5cc(-c6ccccc6)ccc5c4N(c4ccc(C(C)(C)C)cc4-c4ccccc4)c4cc5c(oc6ccccc65)c(c43)-c3cc4c(cc32)oc2ccccc24)cc1 ; CC(C)(C)c1ccc(N2B3c4sc5ccc(C(C)(C)C)cc5c4N(c4ccc(C(C)(C)C)cc4-c4ccccc4)c4cc5c(oc6ccccc65)c(c43)-c3cc4c(cc32)oc2cc3c(cc24)C(C)(C)CCC3(C)C)cc1 ; CC(C)(C)c1ccc(N2c3cc4c(oc5ccccc54)c4c3B(c3sc5cc(-c6ccccc6)ccc5c32)N(c2ccc(-c3ccccc3)cc2)c2cc3oc5cc6c(cc5c3cc2-4)C(C)(C)CCC6(C)C)c(-c2ccccc2)c1] 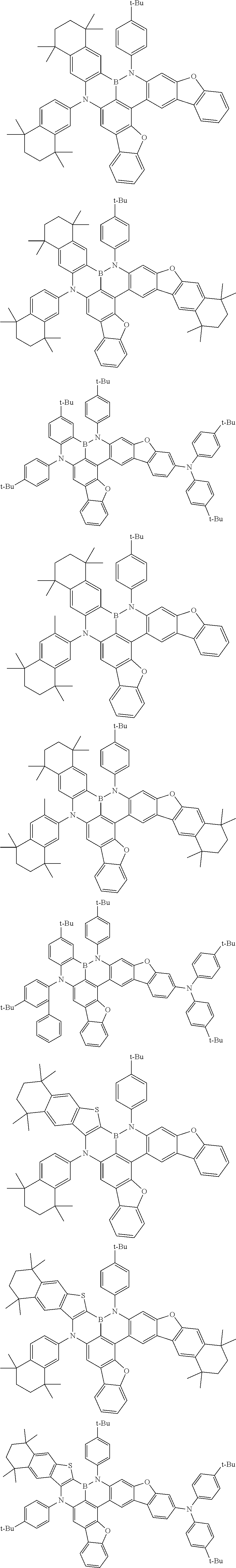 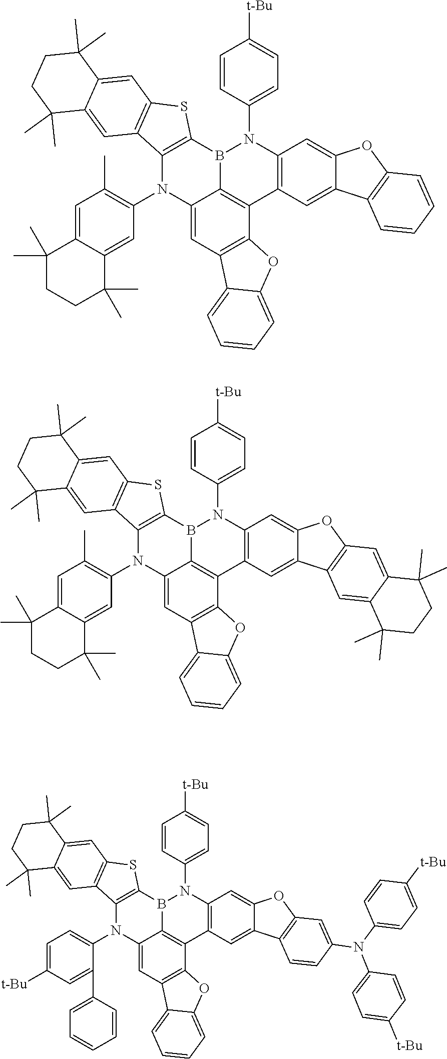 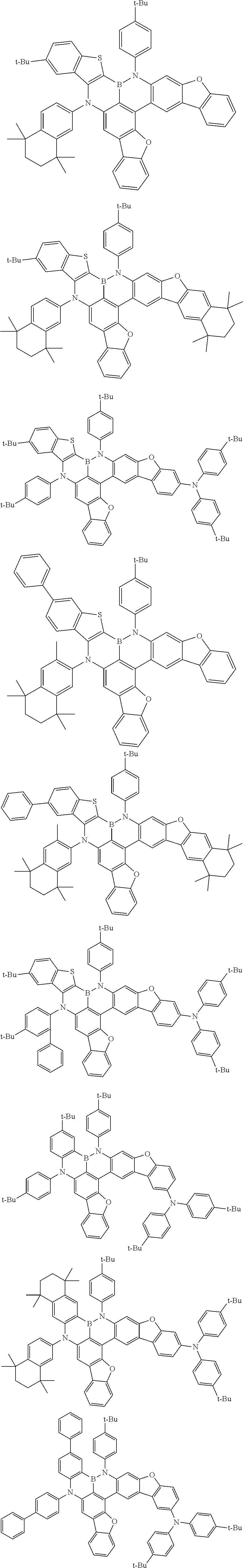 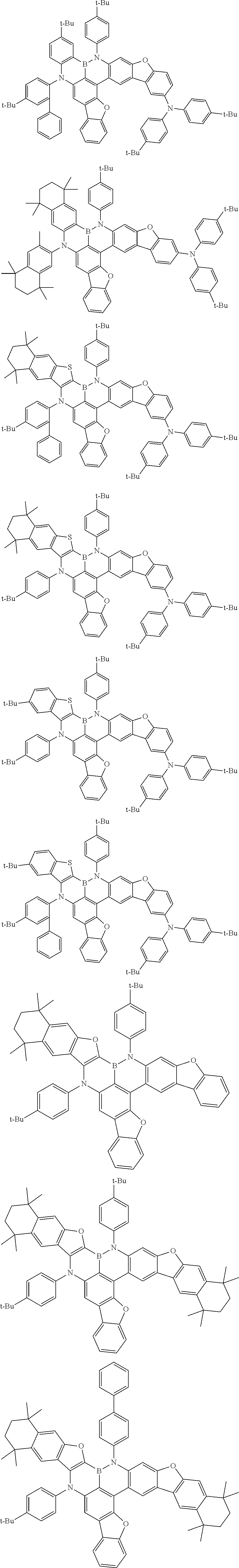 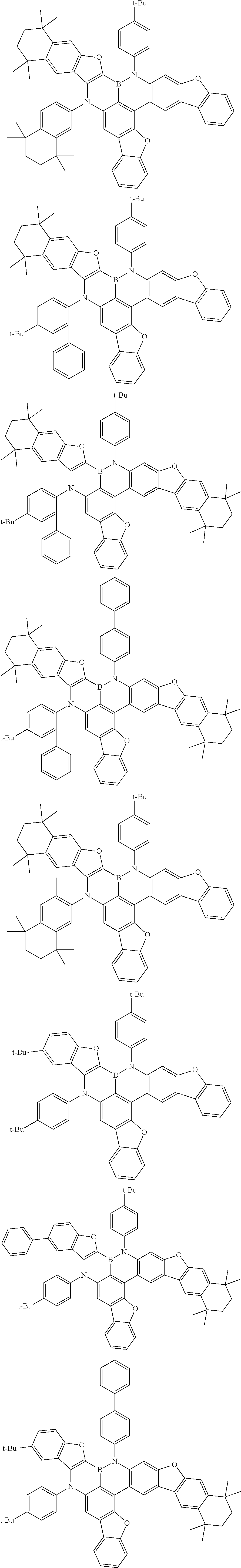 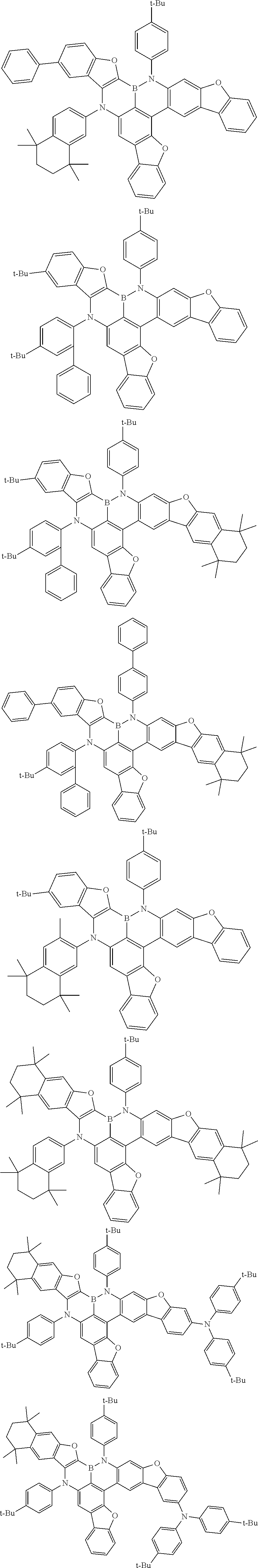 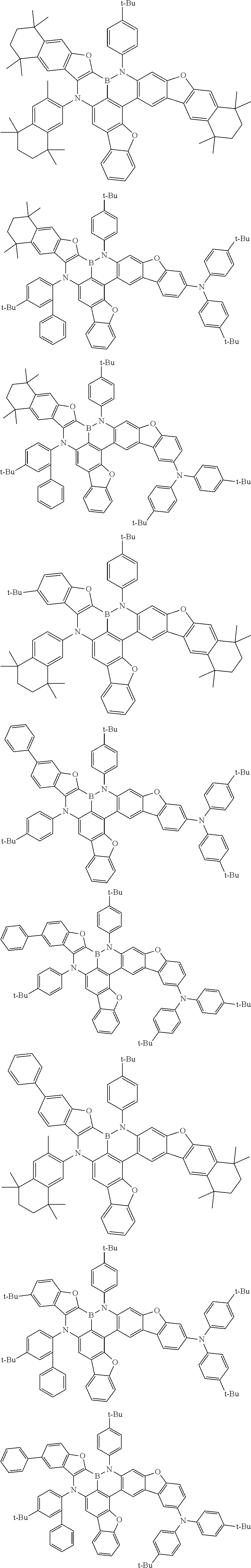 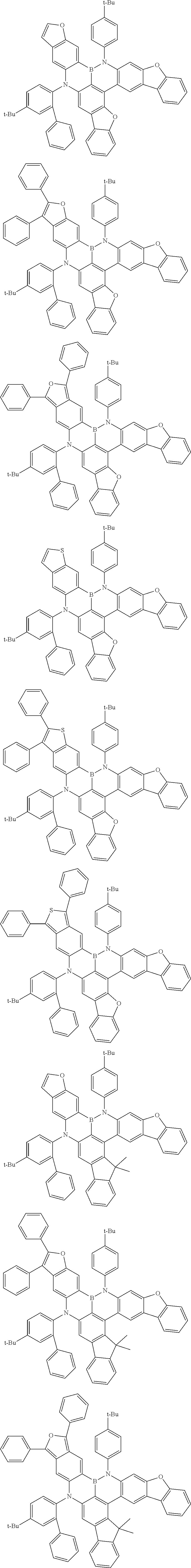 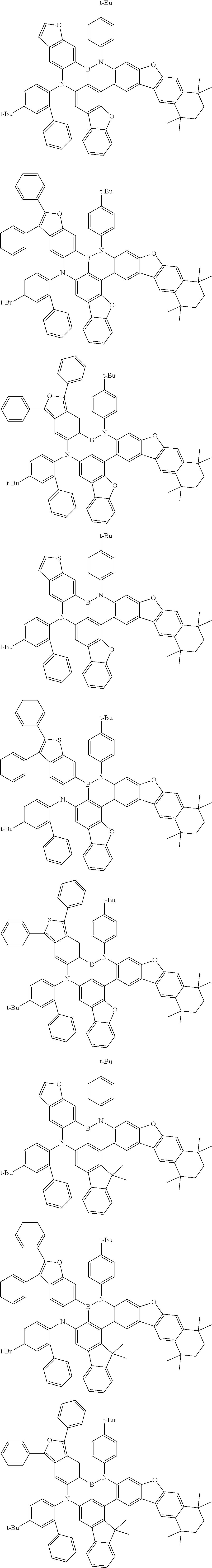 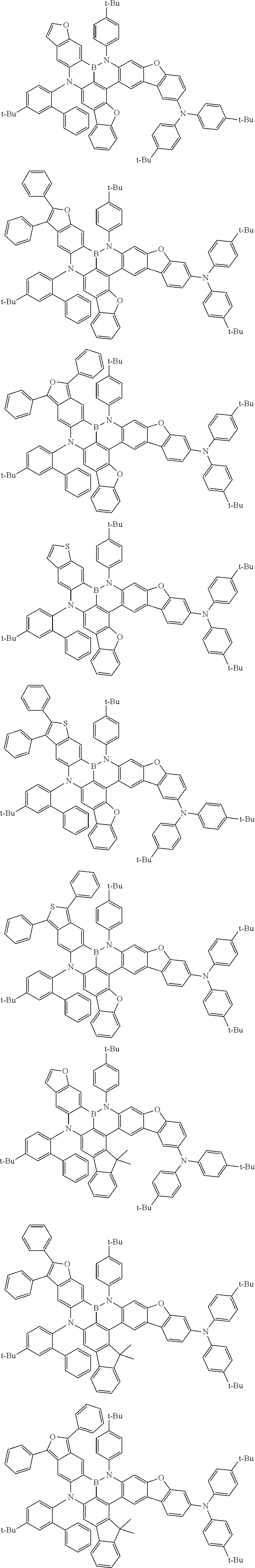 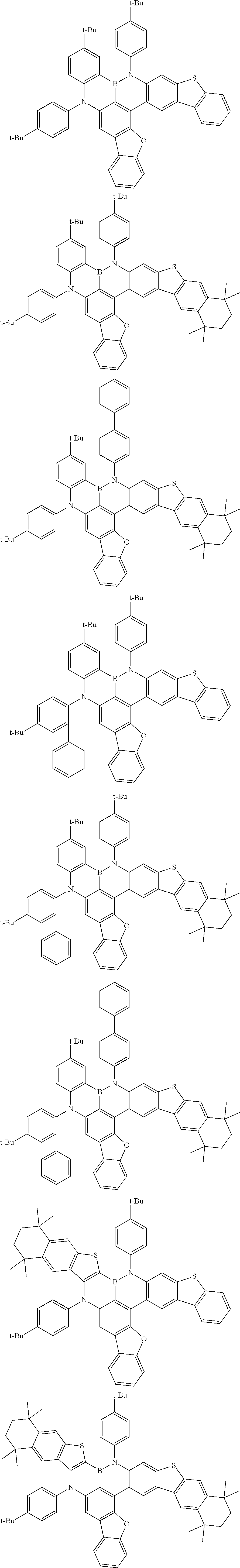 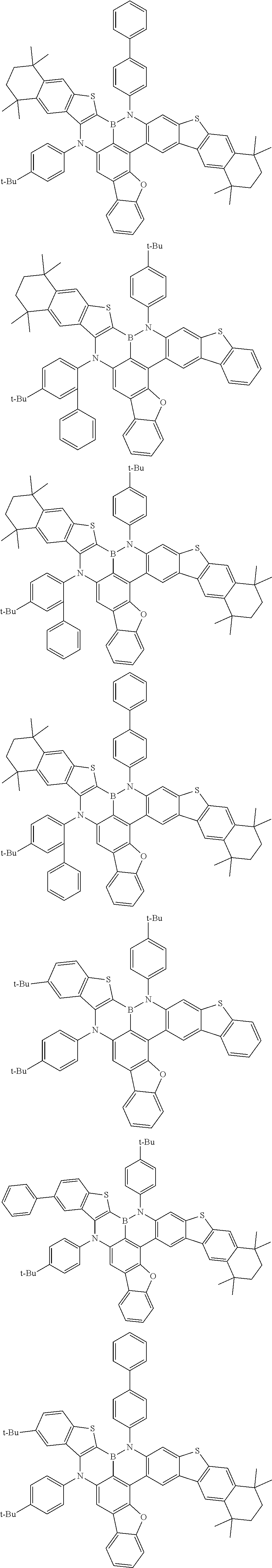 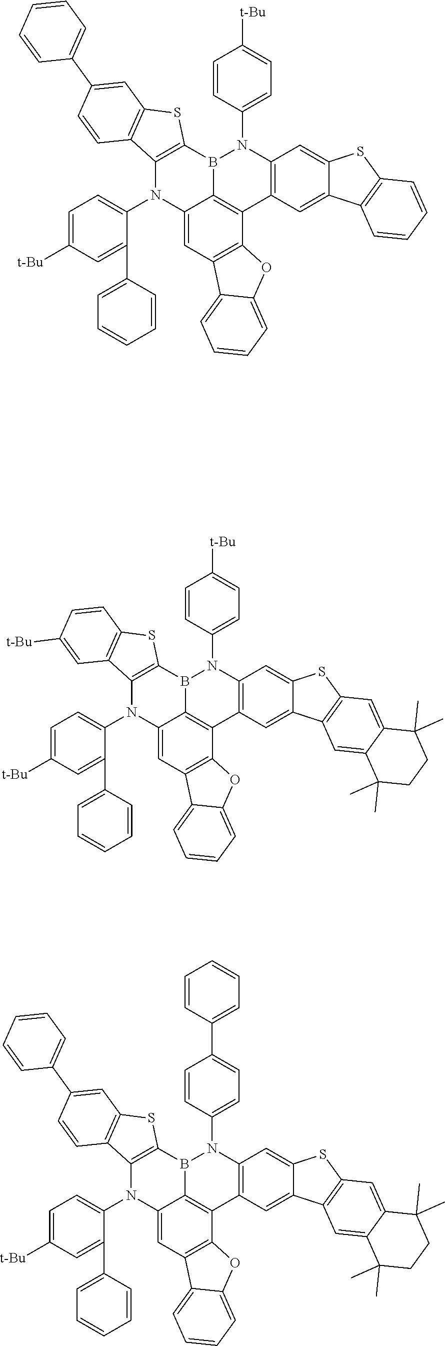 [SMILES: CC(C)(C)c1ccc(N2B3c4sc5cc(-c6ccccc6)ccc5c4N(c4ccc(C(C)(C)C)cc4-c4ccccc4)c4cc5c(oc6ccccc65)c(c43)-c3cc4c(cc32)sc2ccccc24)cc1 ; CC(C)(C)c1ccc(N2B3c4sc5ccc(C(C)(C)C)cc5c4N(c4ccc(C(C)(C)C)cc4-c4ccccc4)c4cc5c(oc6ccccc65)c(c43)-c3cc4c(cc32)sc2cc3c(cc24)C(C)(C)CCC3(C)C)cc1 ; CC(C)(C)c1ccc(N2c3cc4c(oc5ccccc54)c4c3B(c3sc5cc(-c6ccccc6)ccc5c32)N(c2ccc(-c3ccccc3)cc2)c2cc3sc5cc6c(cc5c3cc2-4)C(C)(C)CCC6(C)C)c(-c2ccccc2)c1] 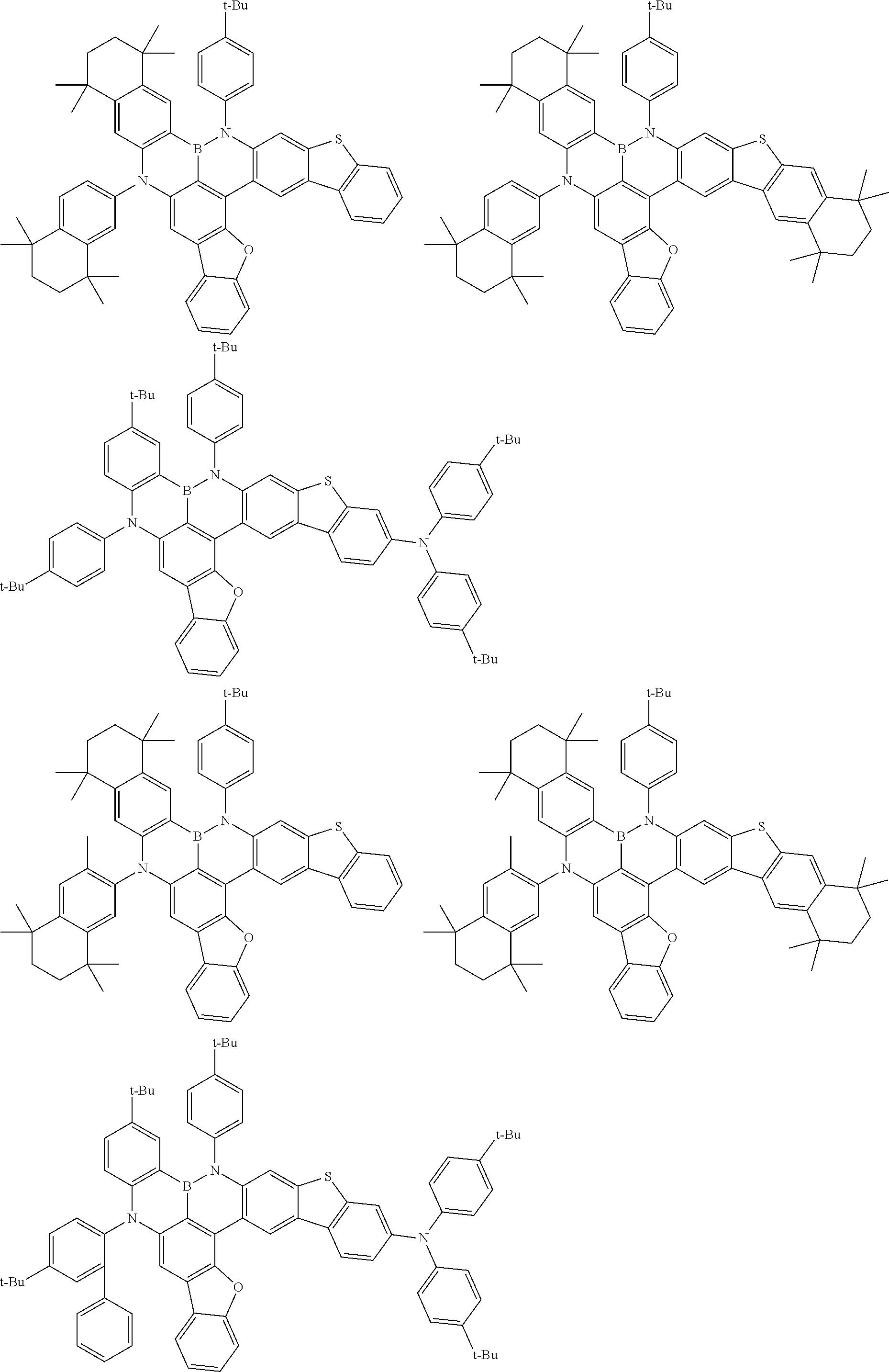 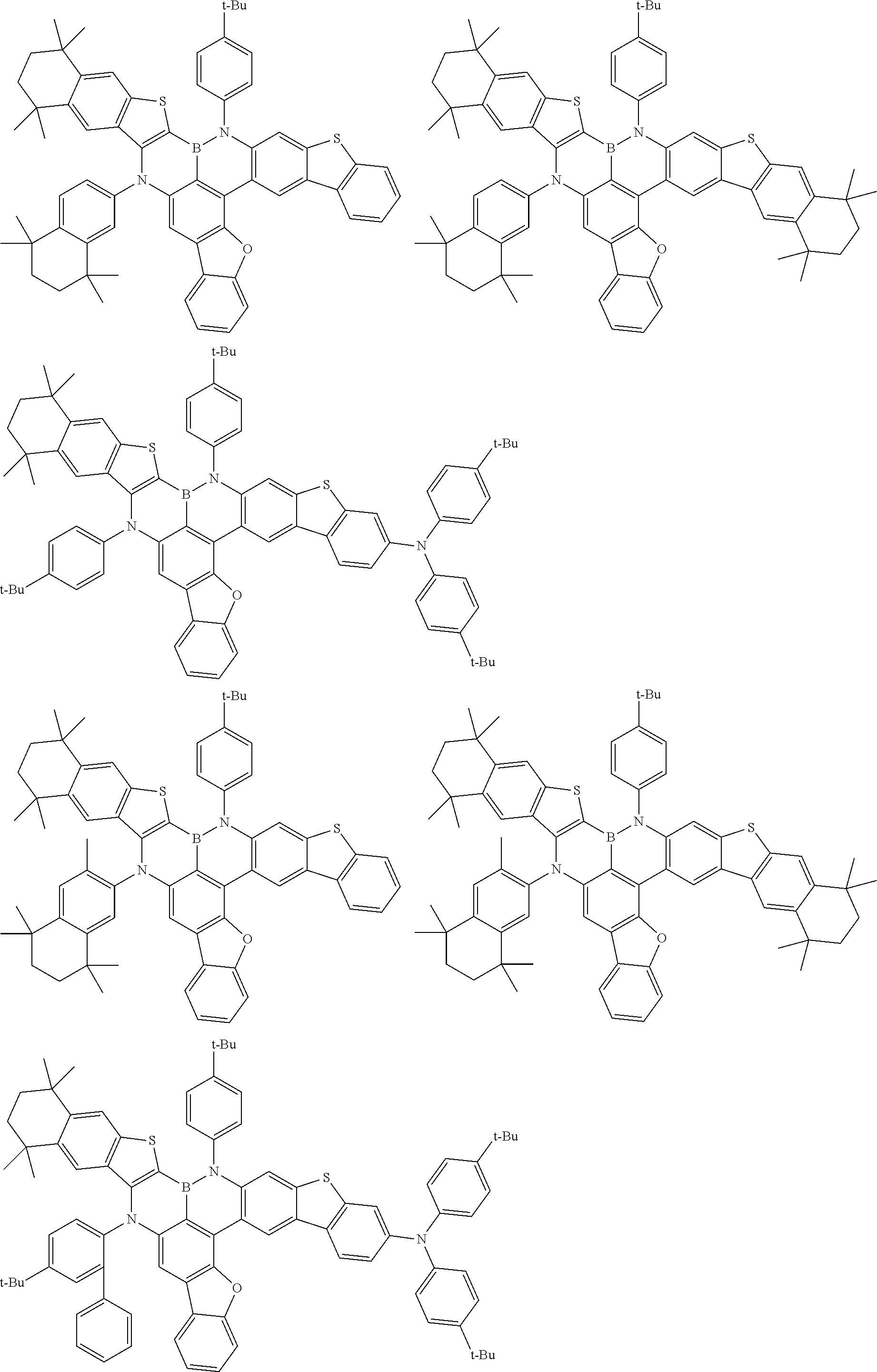 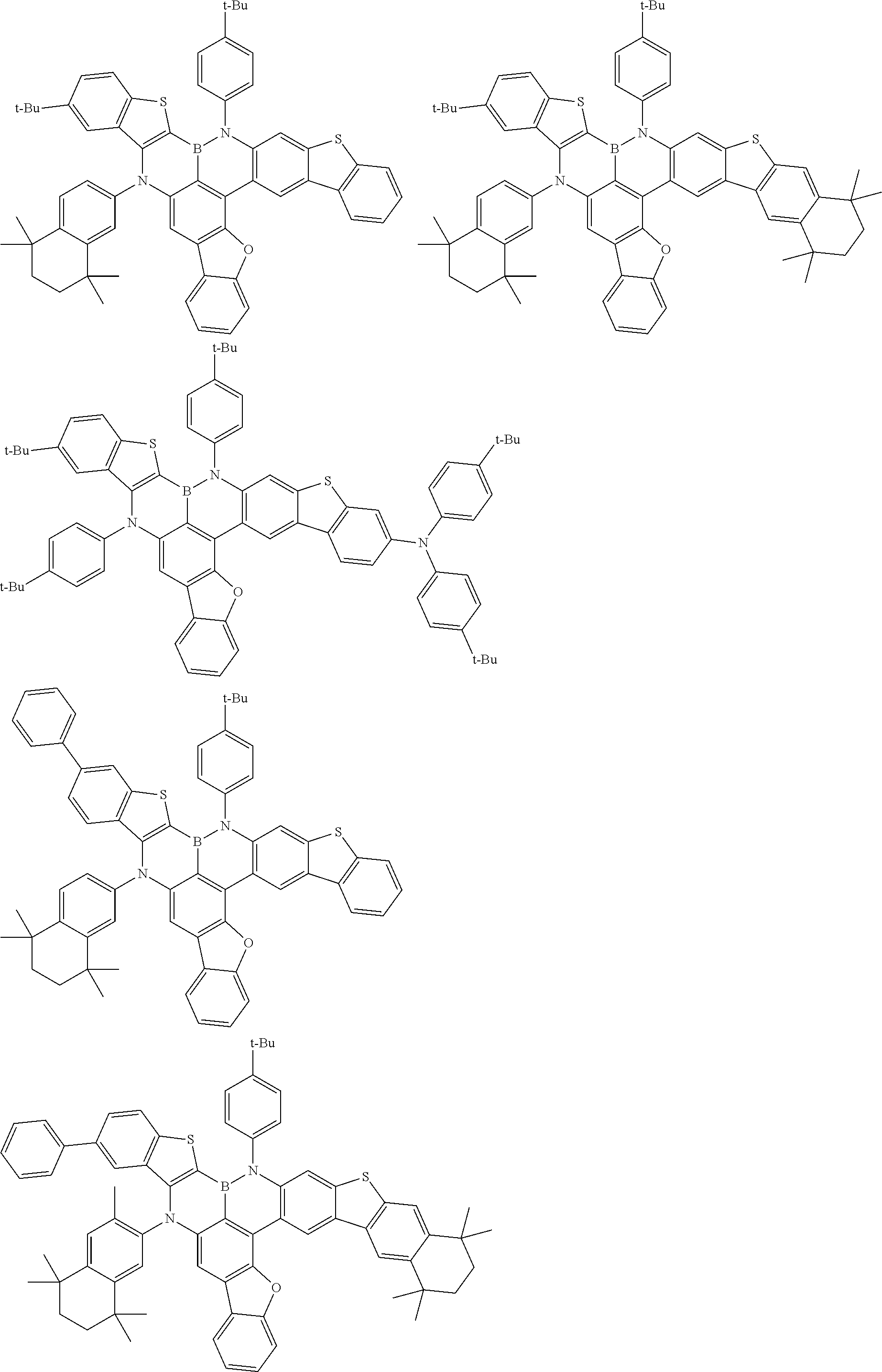 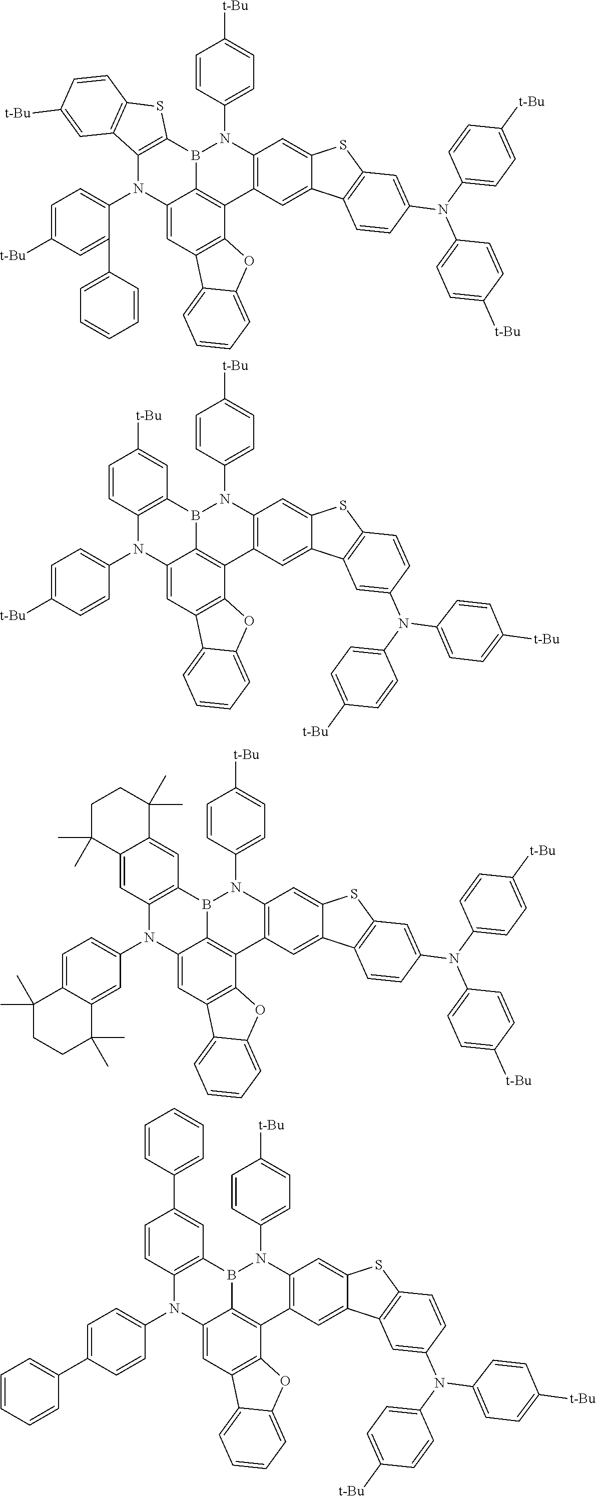 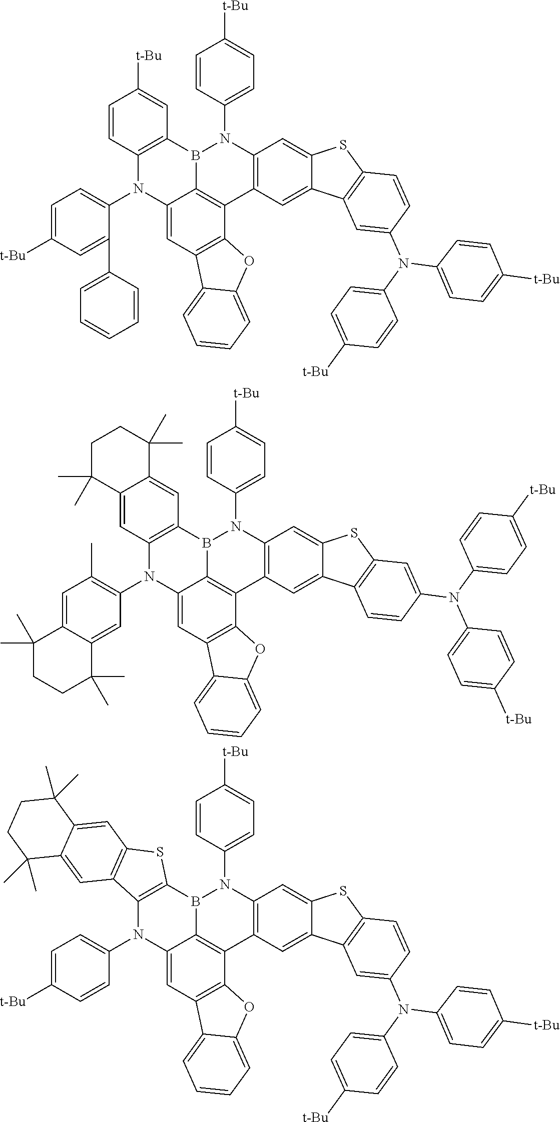 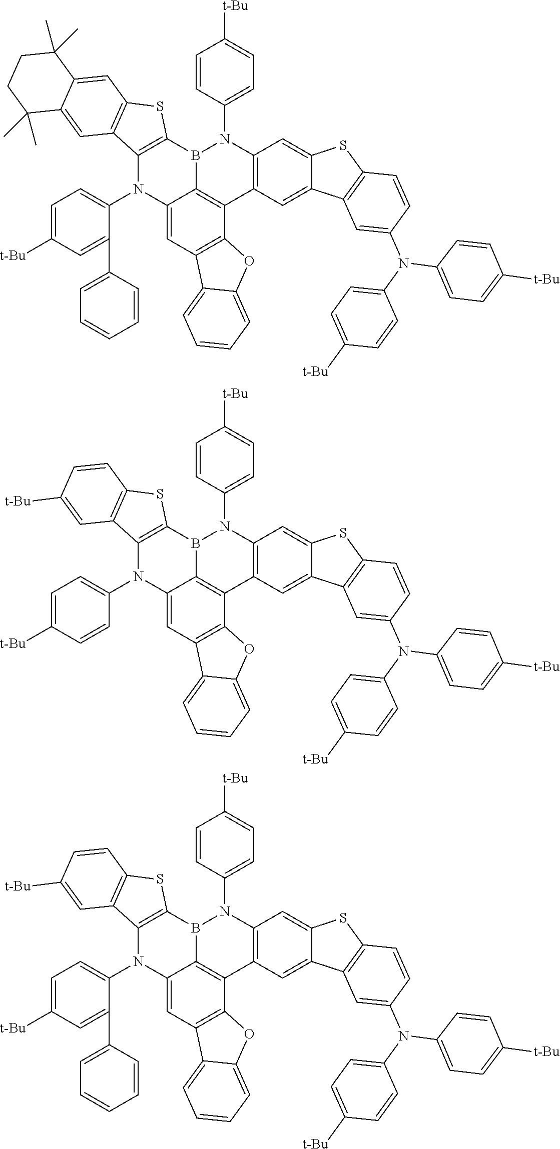 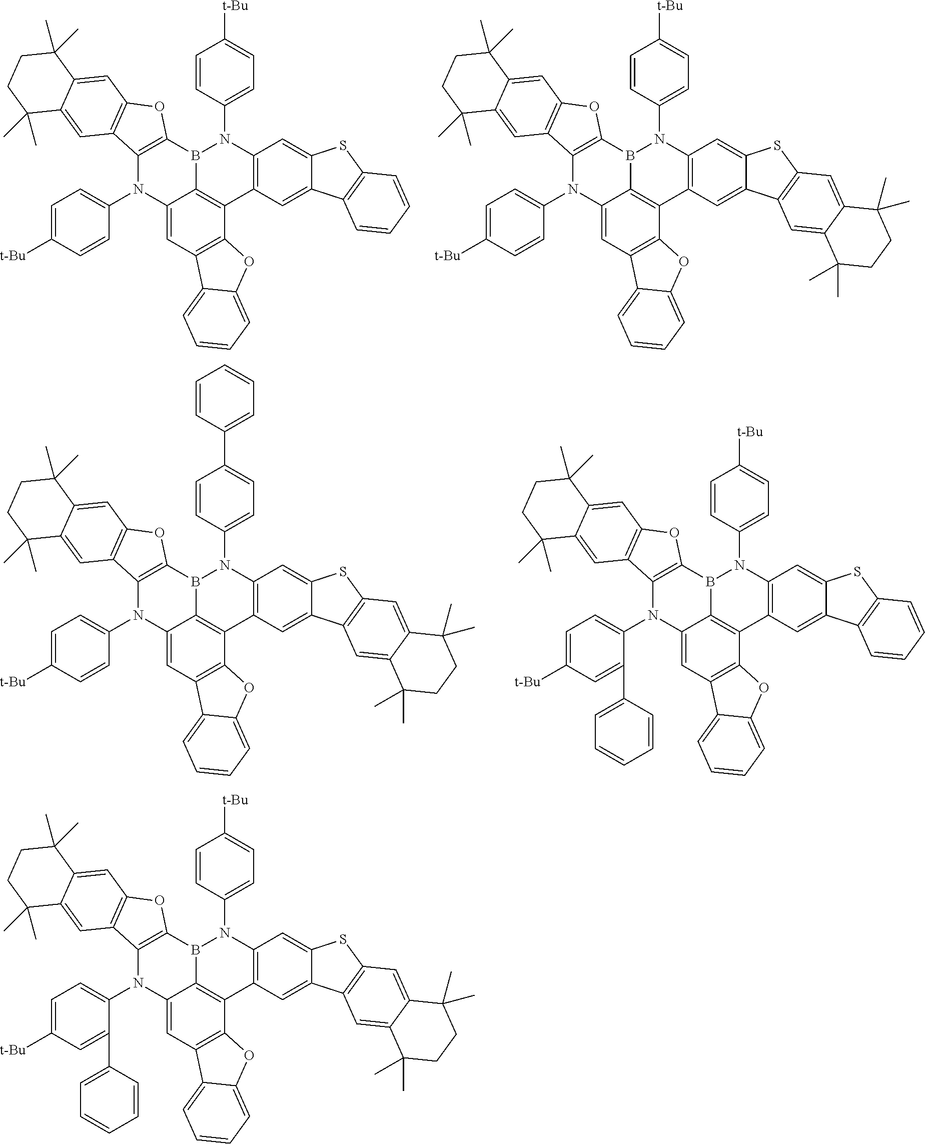 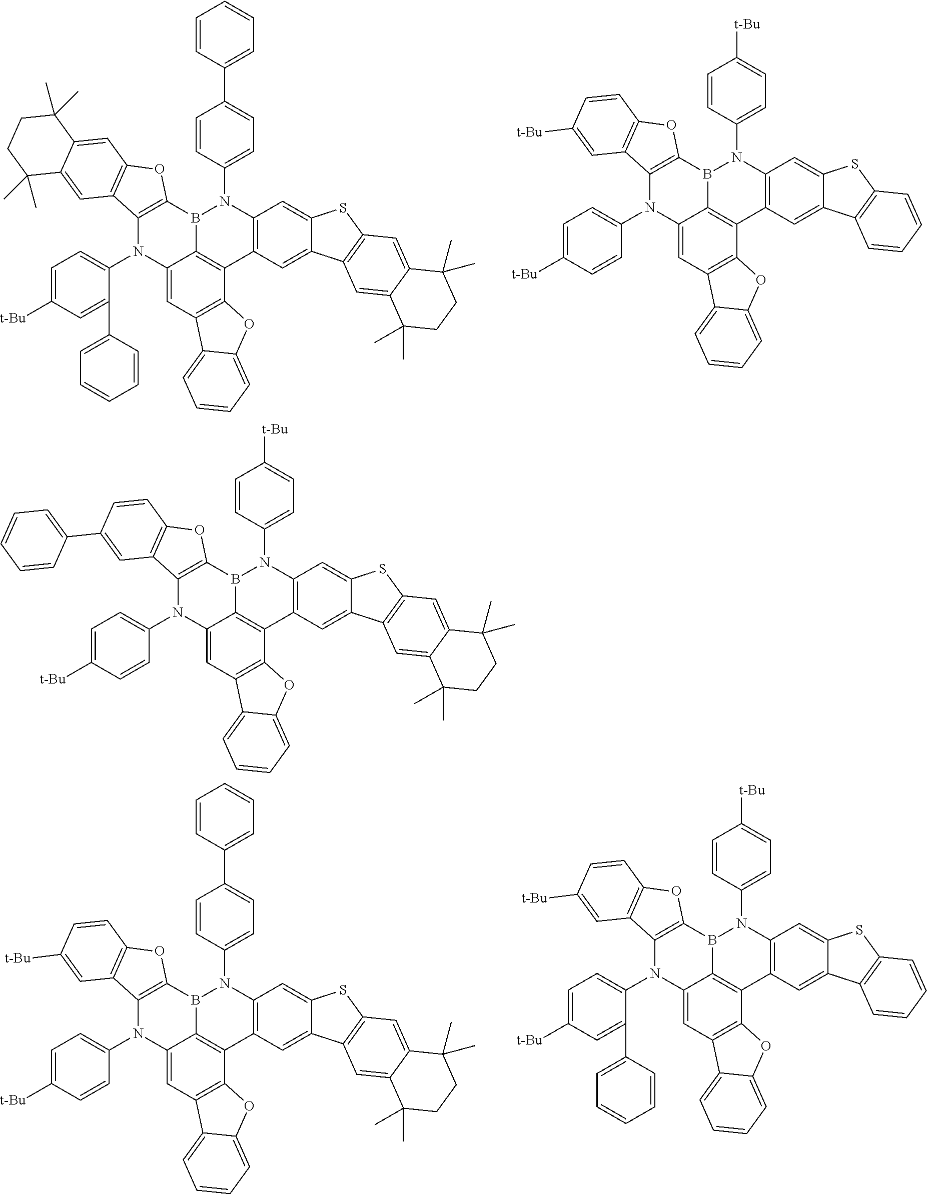 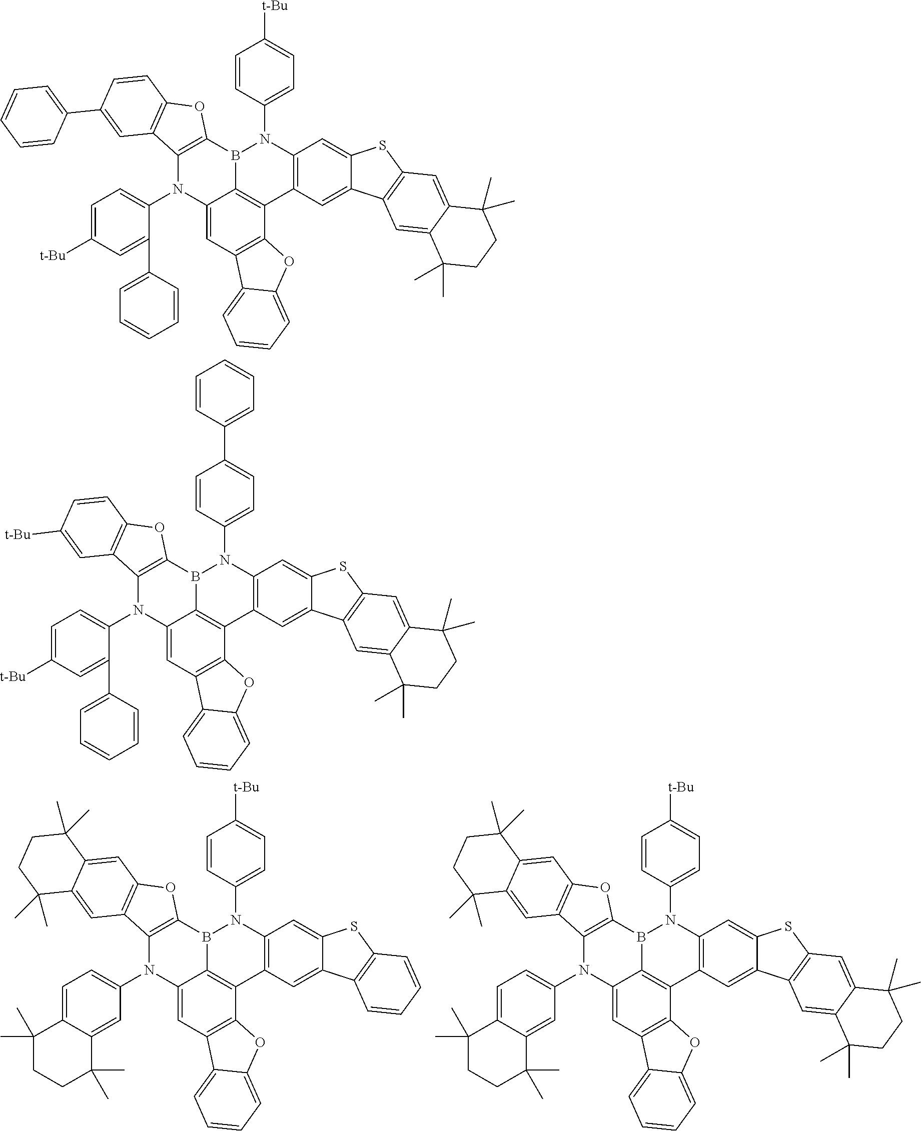 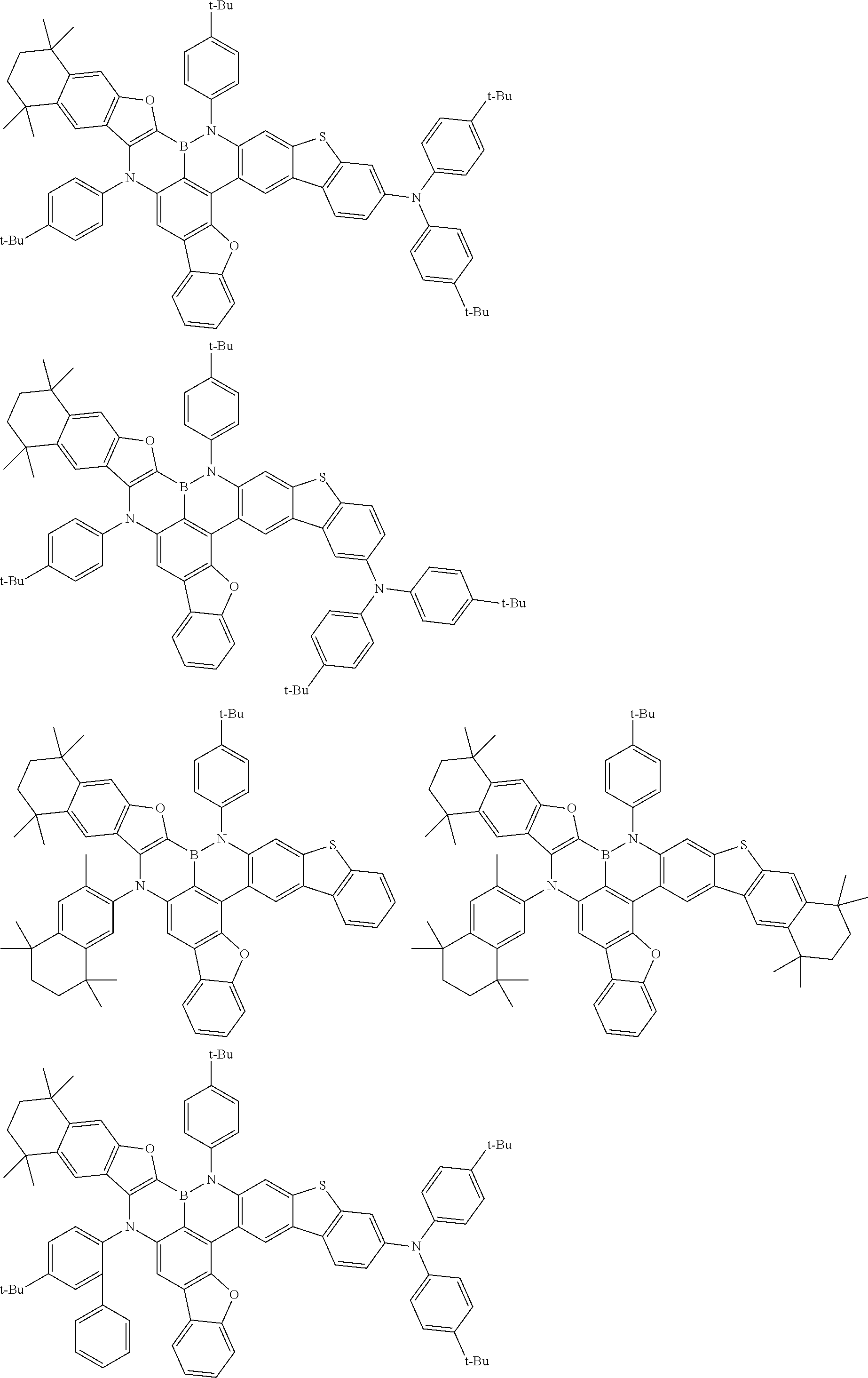 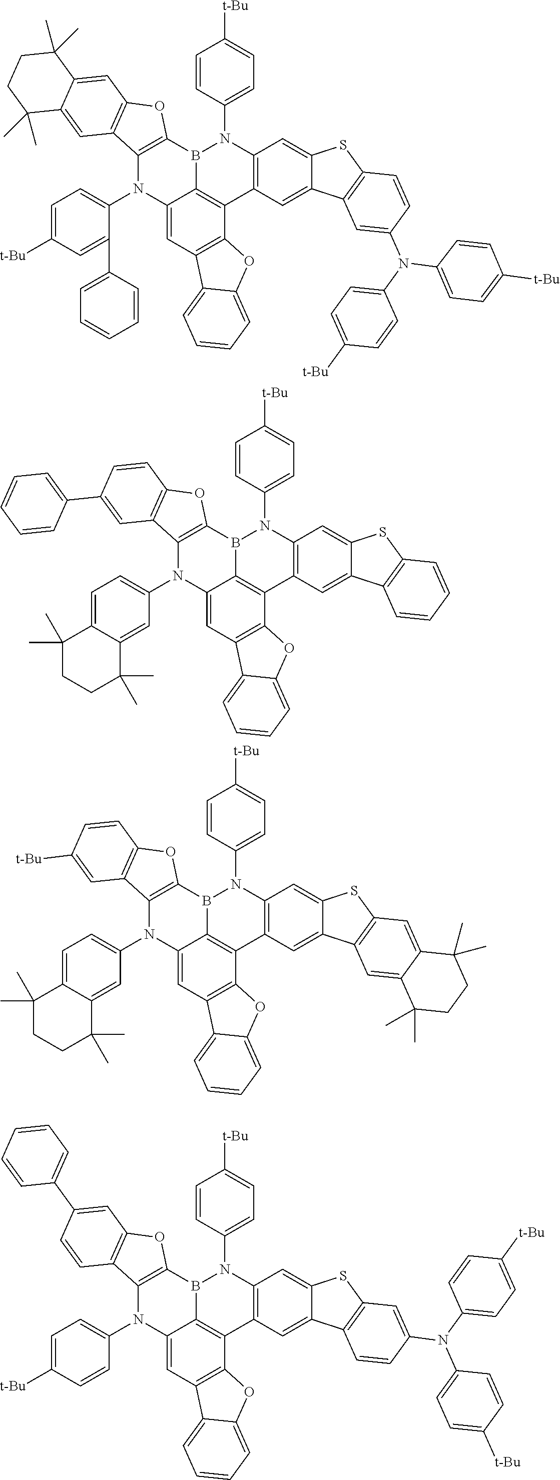 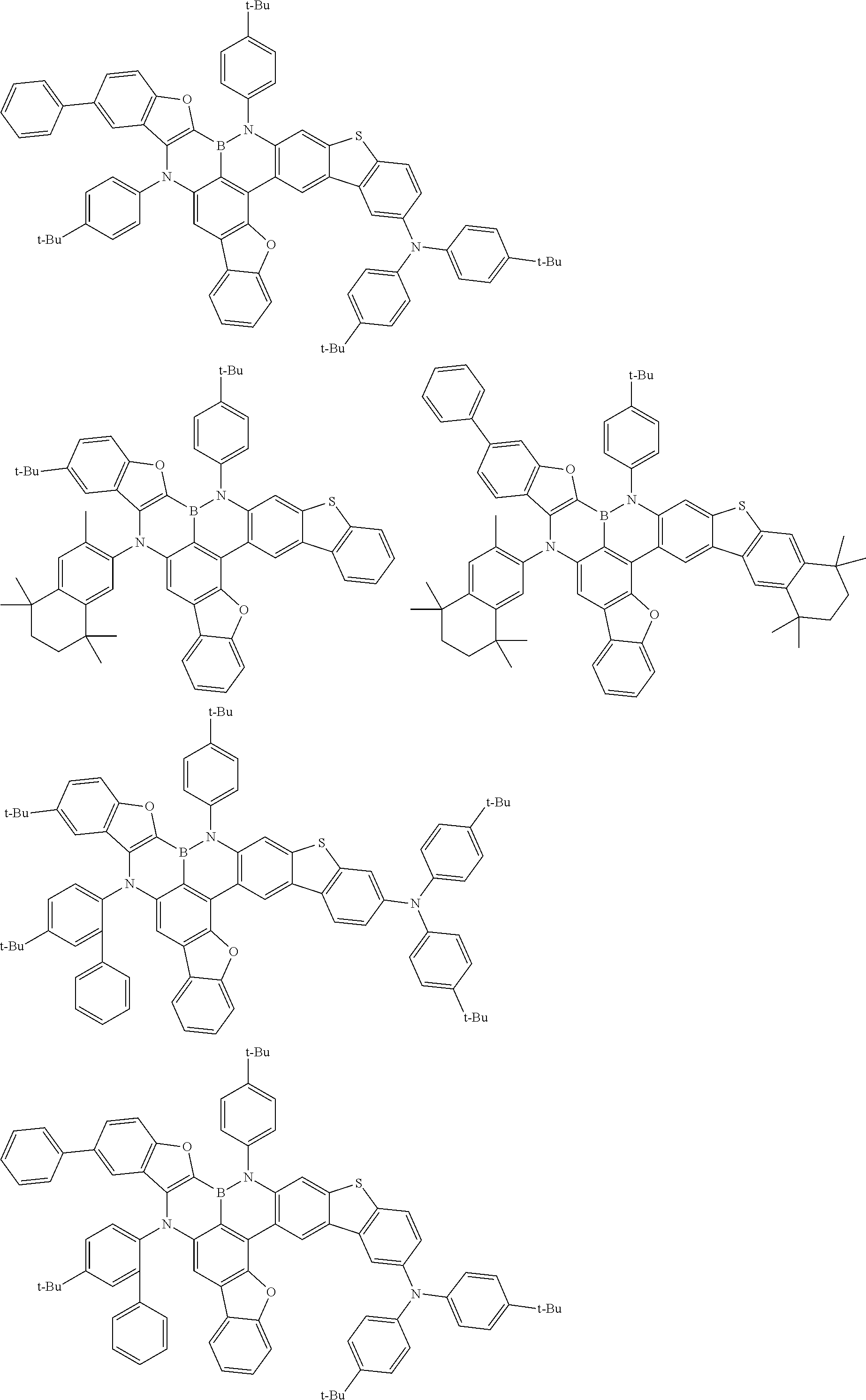 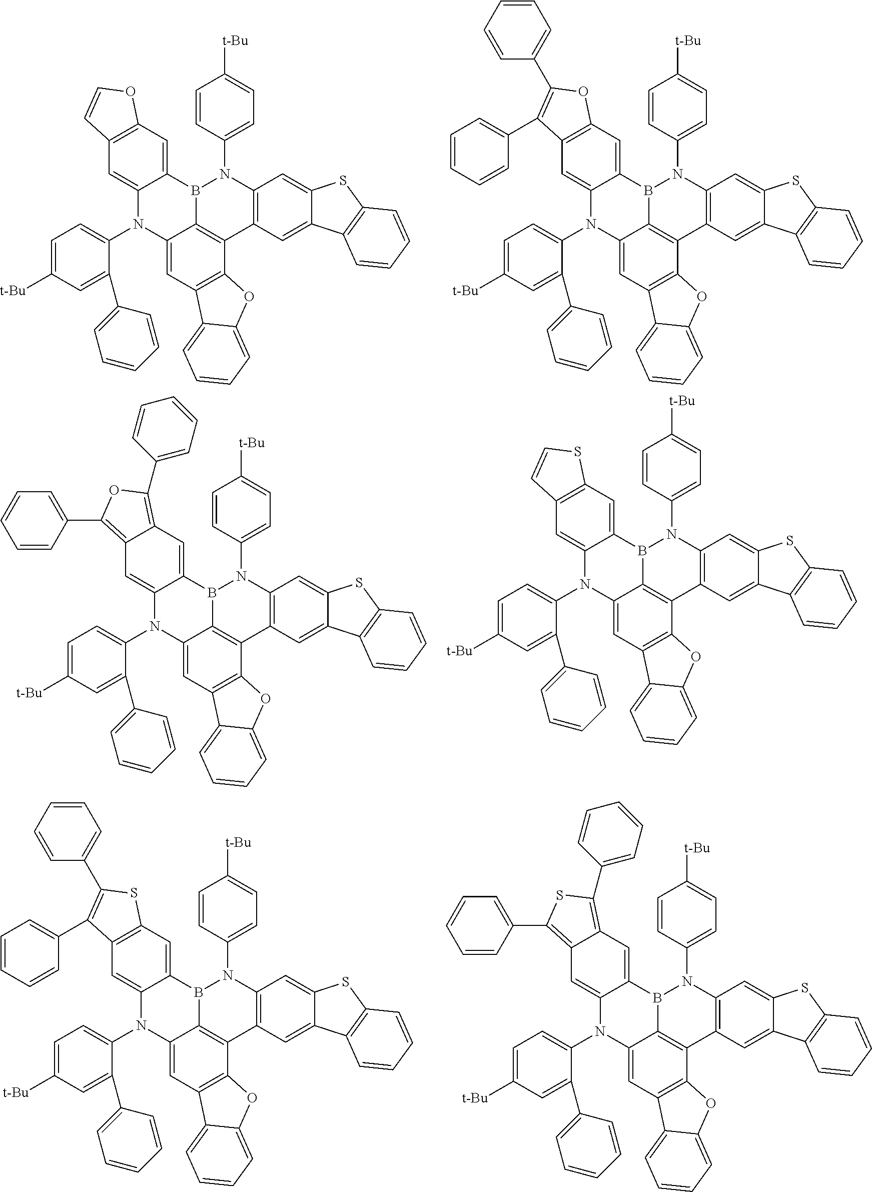 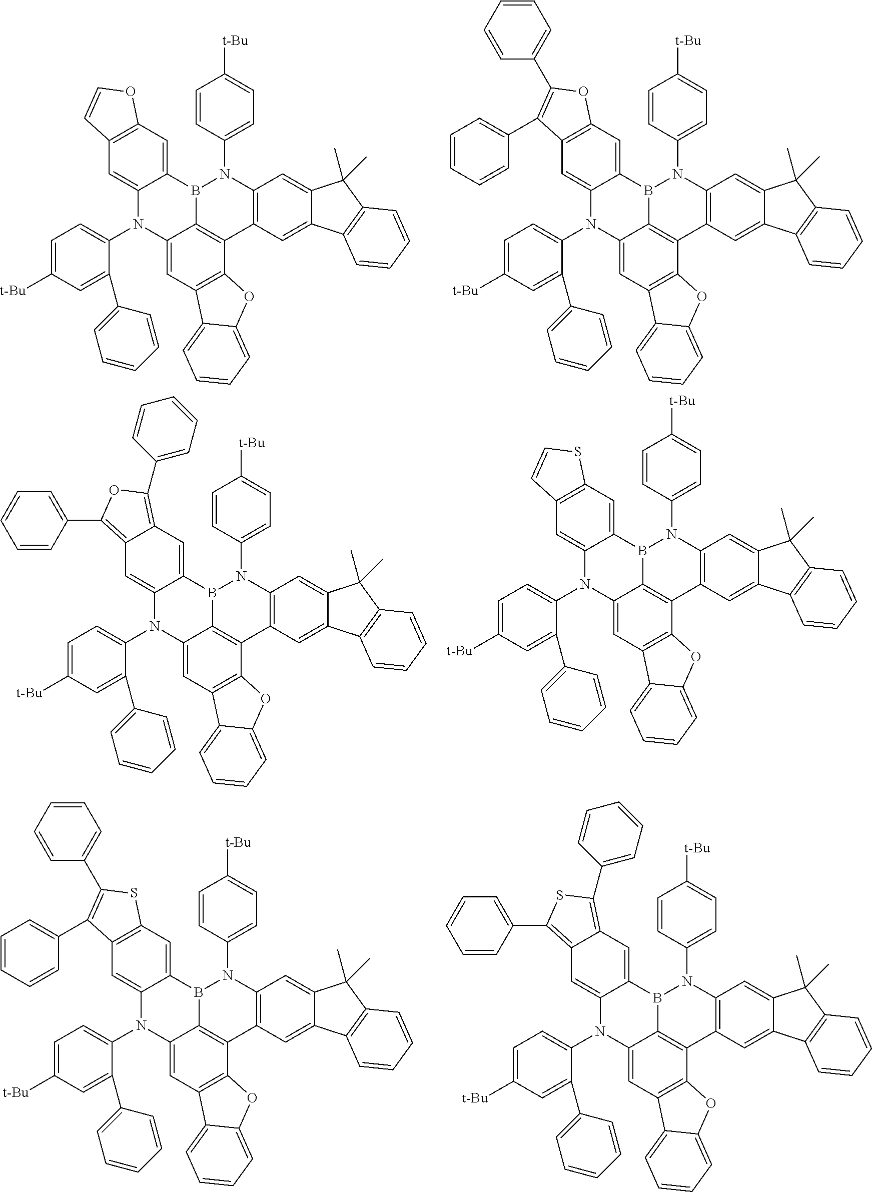 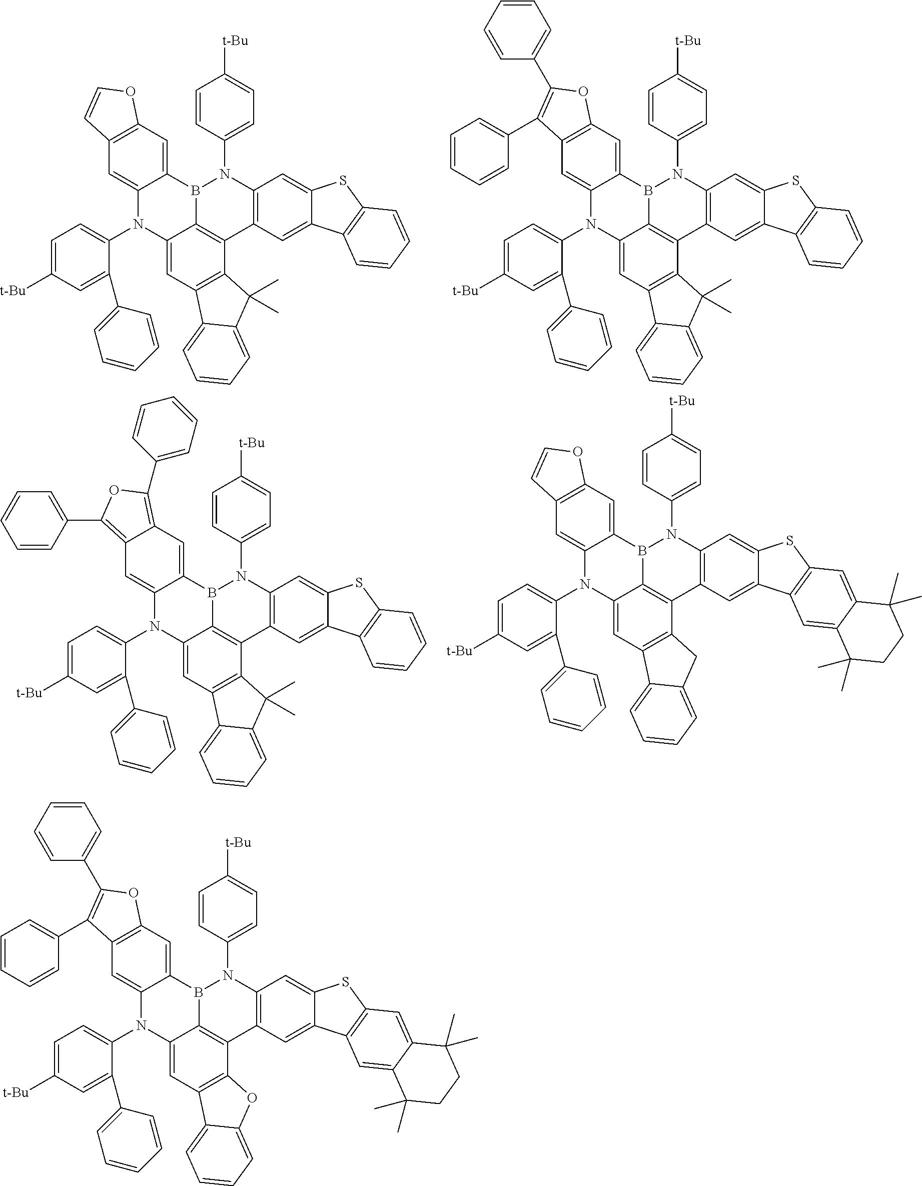 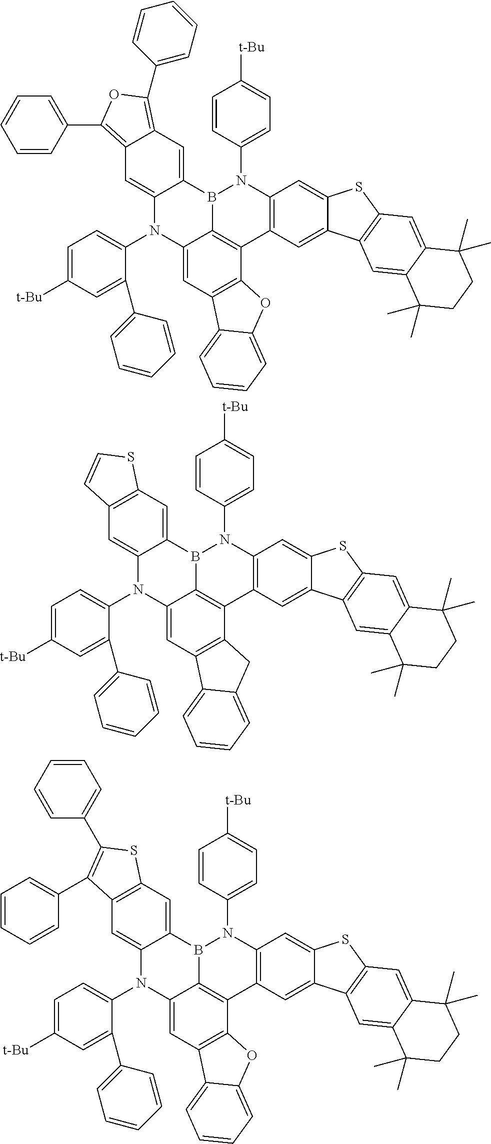 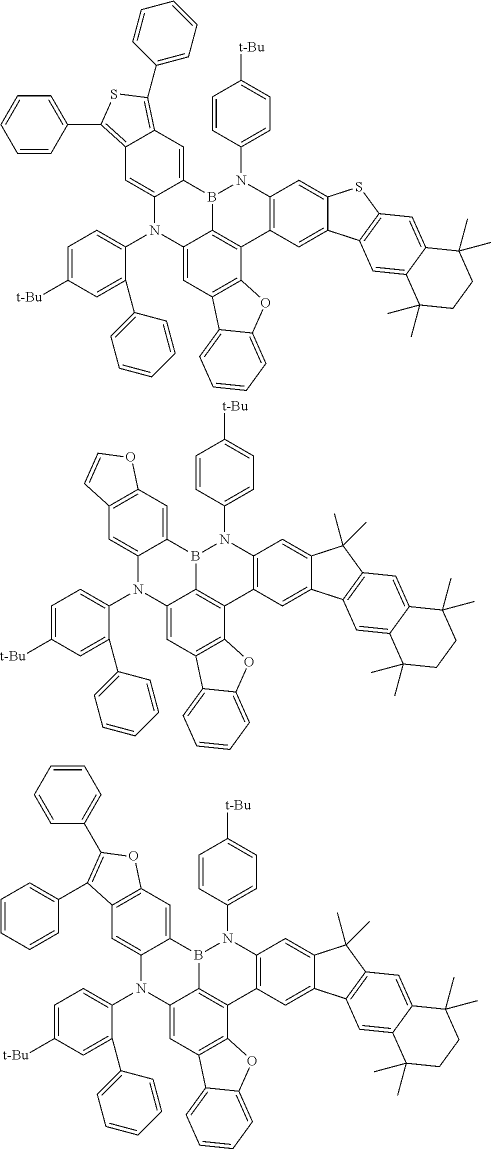 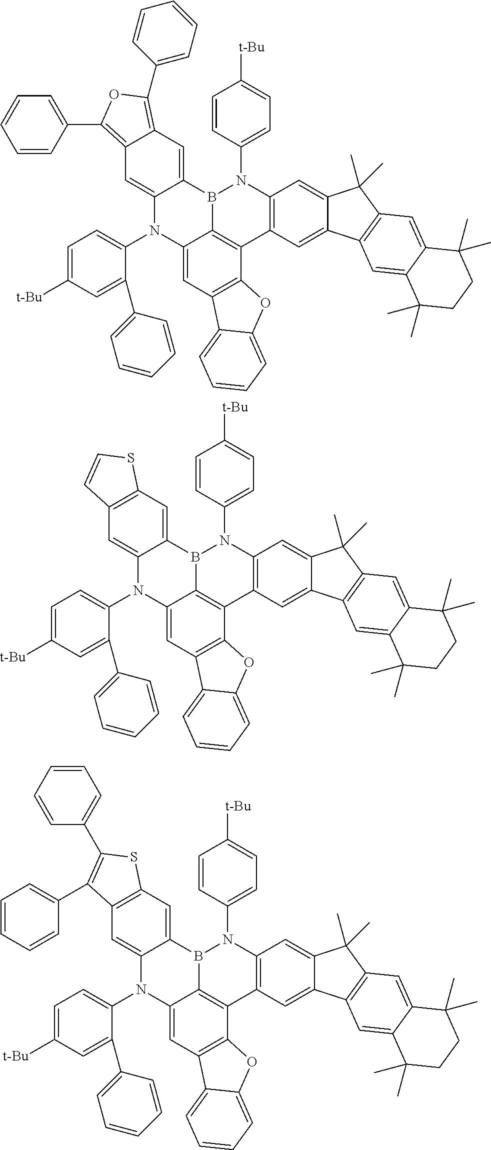 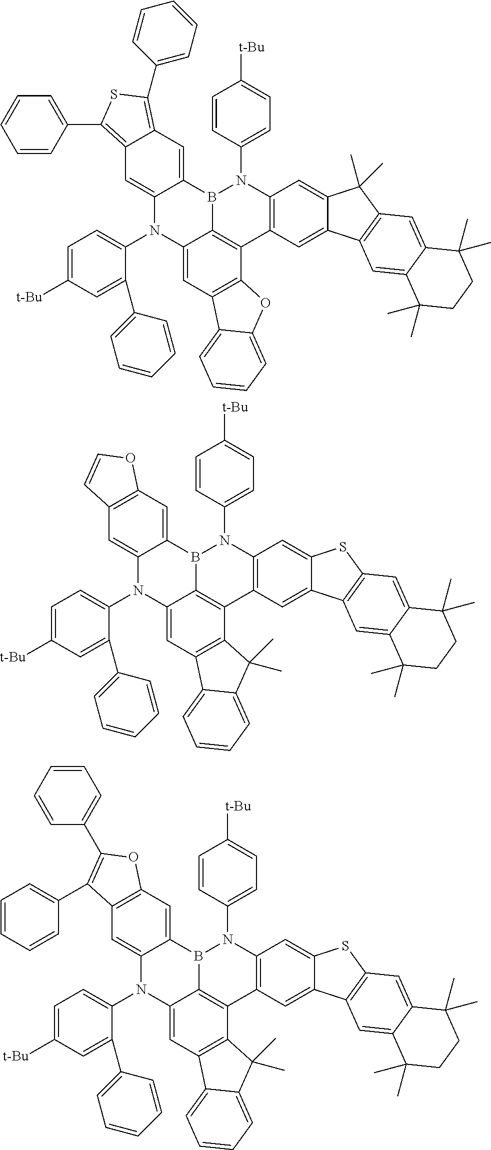 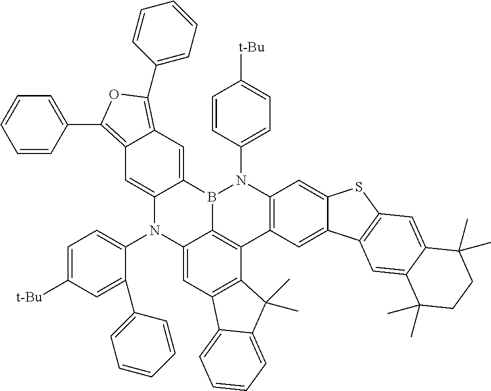 [SMILES: CC(C)(C)c1ccc(N2B3c4cc5c(-c6ccccc6)oc(-c6ccccc6)c5cc4N(c4ccc(C(C)(C)C)cc4-c4ccccc4)c4cc5c(c(c43)-c3cc4c(cc32)sc2cc3c(cc24)C(C)(C)CCC3(C)C)C(C)(C)c2ccccc2-5)cc1] 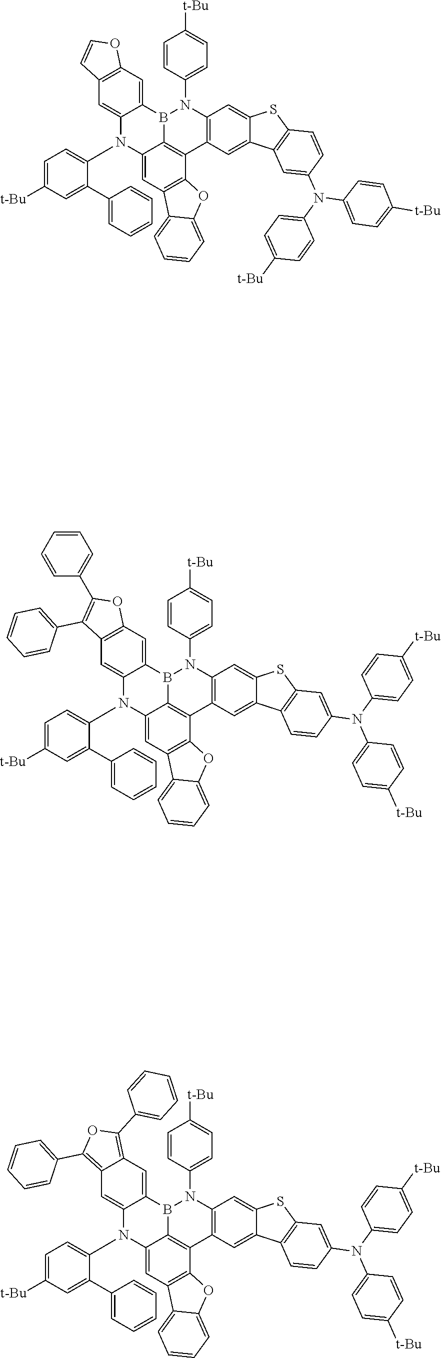 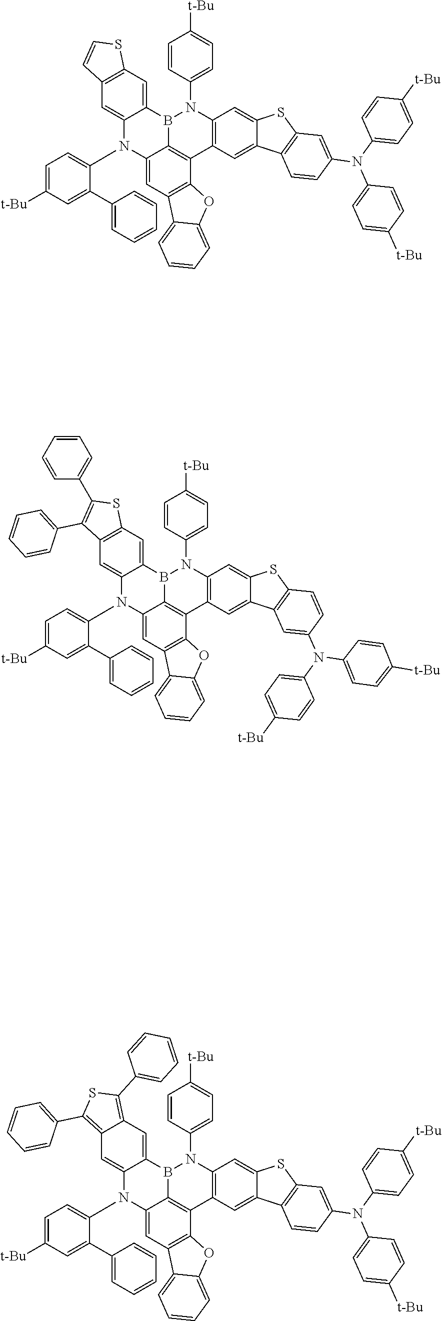 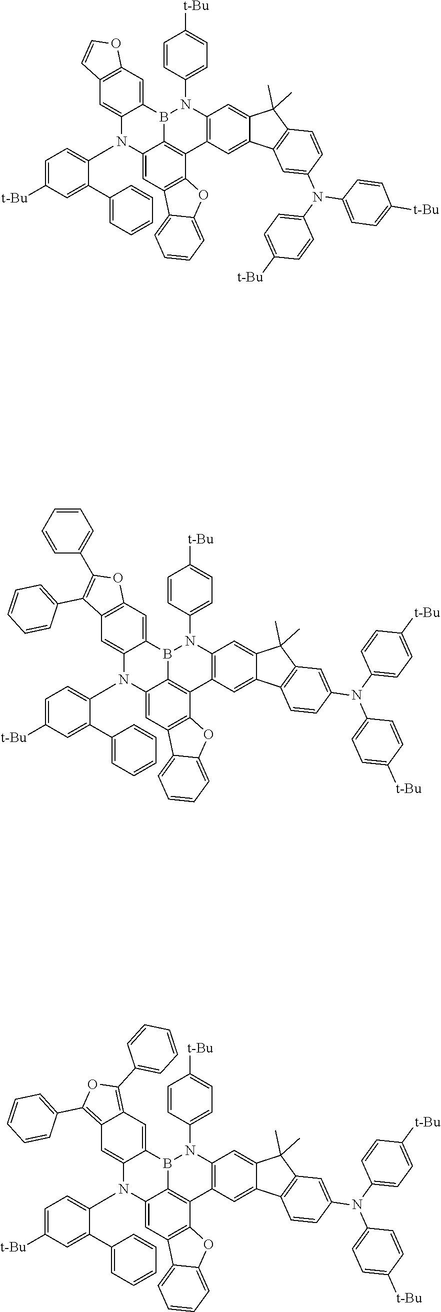 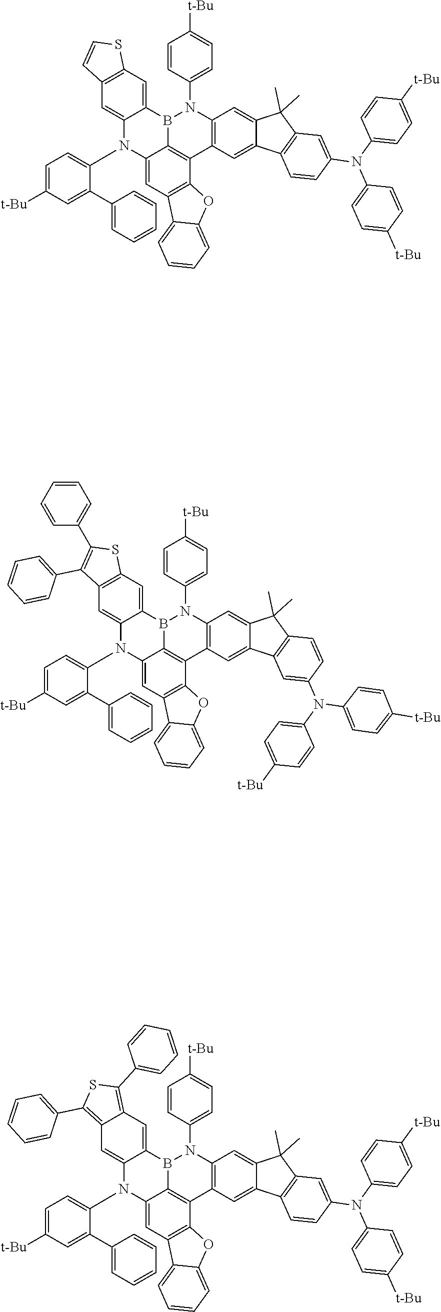 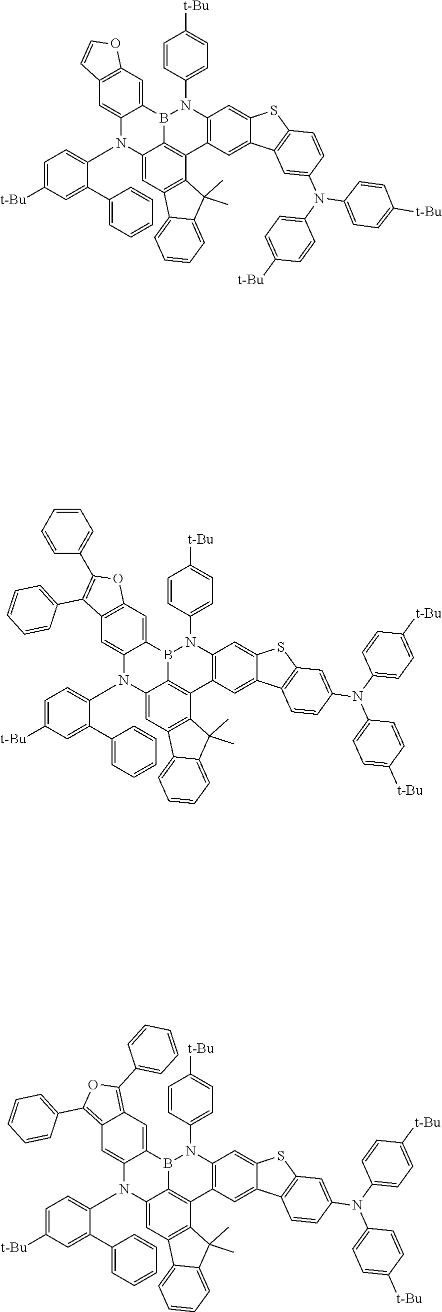 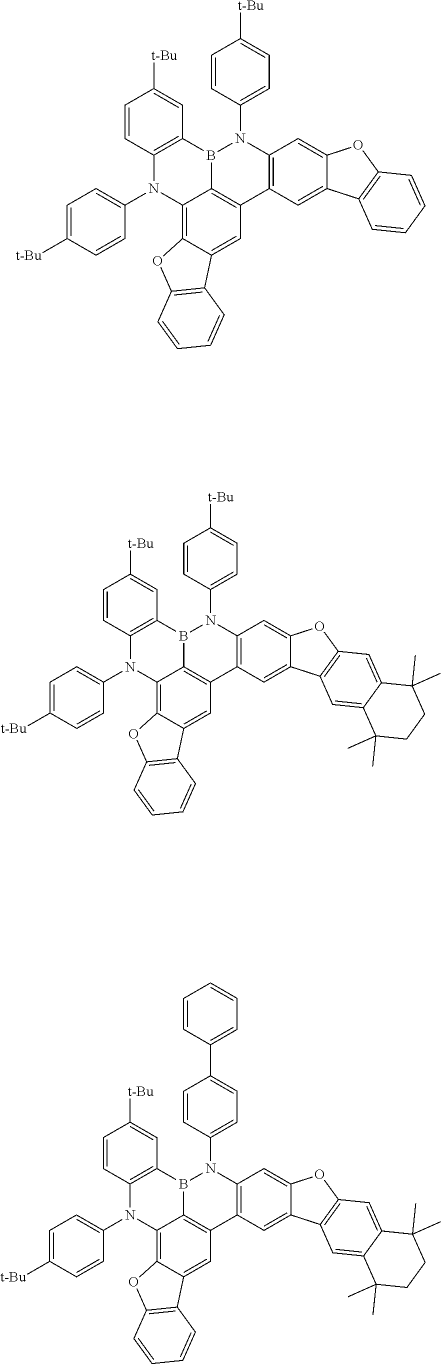 [SMILES: CC(C)(C)c1ccc(N2B3c4cc(C(C)(C)C)ccc4N(c4ccc(C(C)(C)C)cc4)c4c3c(cc3c4oc4ccccc43)-c3cc4c(cc32)oc2ccccc24)cc1 ; CC(C)(C)c1ccc(N2B3c4cc(C(C)(C)C)ccc4N(c4ccc(C(C)(C)C)cc4)c4c3c(cc3c4oc4ccccc43)-c3cc4c(cc32)oc2cc3c(cc24)C(C)(C)CCC3(C)C)cc1 ; CC(C)(C)c1ccc(N2c3ccc(C(C)(C)C)cc3B3c4c(cc5c(oc6ccccc65)c42)-c2cc4c(cc2N3c2ccc(-c3ccccc3)cc2)oc2cc3c(cc24)C(C)(C)CCC3(C)C)cc1] 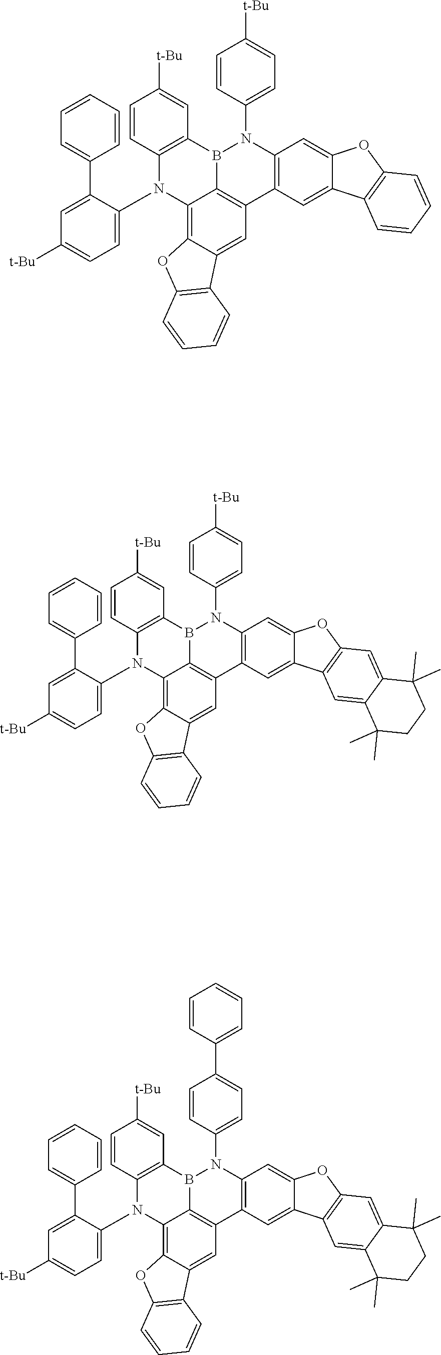 [SMILES: CC(C)(C)c1ccc(N2B3c4cc(C(C)(C)C)ccc4N(c4ccc(C(C)(C)C)cc4-c4ccccc4)c4c3c(cc3c4oc4ccccc43)-c3cc4c(cc32)oc2ccccc24)cc1 ; CC(C)(C)c1ccc(N2B3c4cc(C(C)(C)C)ccc4N(c4ccc(C(C)(C)C)cc4-c4ccccc4)c4c3c(cc3c4oc4ccccc43)-c3cc4c(cc32)oc2cc3c(cc24)C(C)(C)CCC3(C)C)cc1 ; CC(C)(C)c1ccc2c(c1)B1c3c(cc4c(oc5ccccc54)c3N2c2ccc(C(C)(C)C)cc2-c2ccccc2)-c2cc3c(cc2N1c1ccc(-c2ccccc2)cc1)oc1cc2c(cc13)C(C)(C)CCC2(C)C] 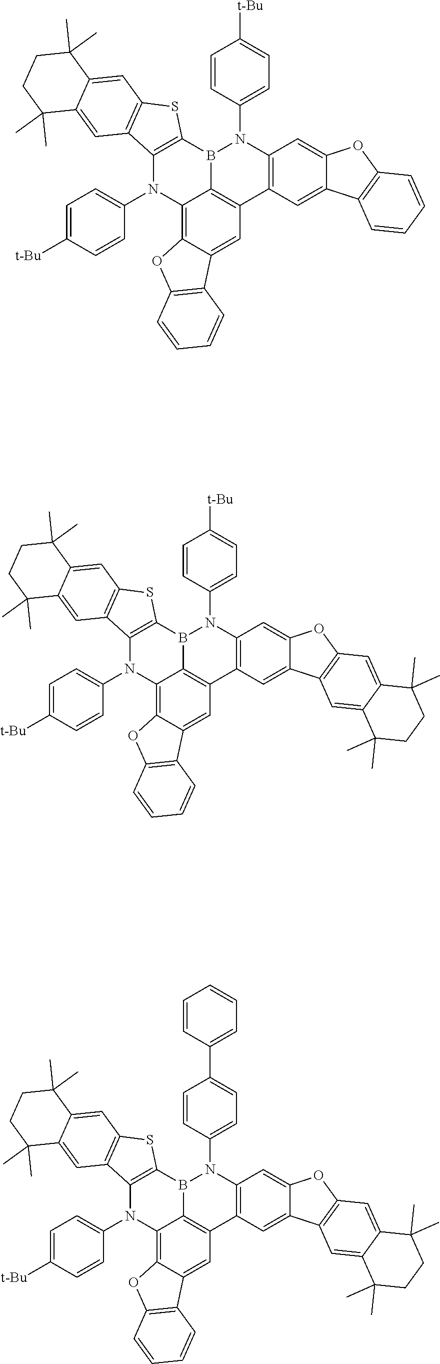 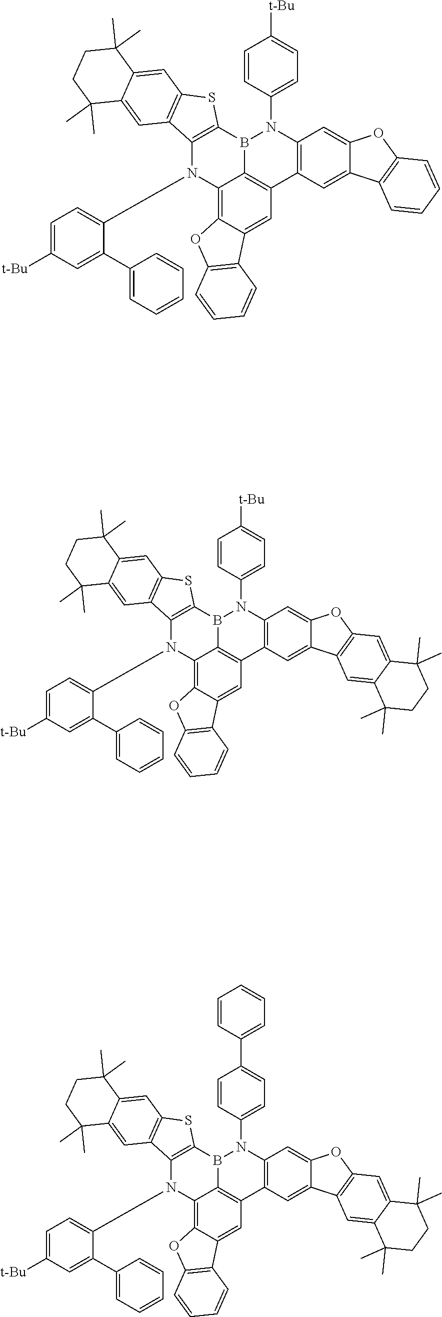 [SMILES: CC(C)(C)c1ccc(N2B3c4sc5cc6c(cc5c4N(c4ccc(C(C)(C)C)cc4-c4ccccc4)c4c3c(cc3c4oc4ccccc43)-c3cc4c(cc32)oc2ccccc24)C(C)(C)CCC6(C)C)cc1 ; CC(C)(C)c1ccc(N2B3c4sc5cc6c(cc5c4N(c4ccc(C(C)(C)C)cc4-c4ccccc4)c4c3c(cc3c4oc4ccccc43)-c3cc4c(cc32)oc2cc3c(cc24)C(C)(C)CCC3(C)C)C(C)(C)CCC6(C)C)cc1 ; CC(C)(C)c1ccc(N2c3c(sc4cc5c(cc34)C(C)(C)CCC5(C)C)B3c4c(cc5c(oc6ccccc65)c42)-c2cc4c(cc2N3c2ccc(-c3ccccc3)cc2)oc2cc3c(cc24)C(C)(C)CCC3(C)C)c(-c2ccccc2)c1] 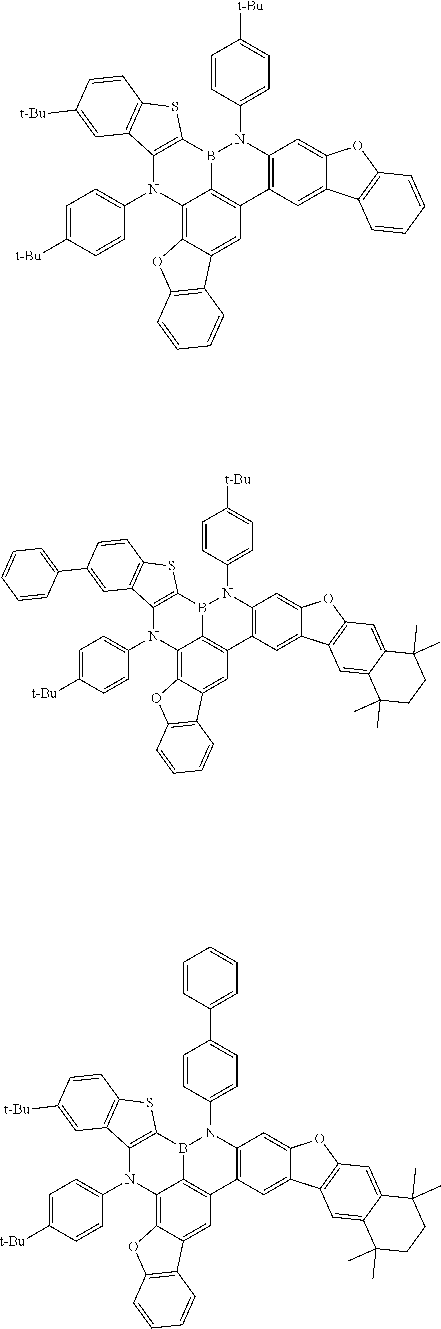 [SMILES: CC(C)(C)c1ccc(N2B3c4sc5ccc(C(C)(C)C)cc5c4N(c4ccc(C(C)(C)C)cc4)c4c3c(cc3c4oc4ccccc43)-c3cc4c(cc32)oc2ccccc24)cc1 ; CC(C)(C)c1ccc(N2B3c4sc5ccc(-c6ccccc6)cc5c4N(c4ccc(C(C)(C)C)cc4)c4c3c(cc3c4oc4ccccc43)-c3cc4c(cc32)oc2cc3c(cc24)C(C)(C)CCC3(C)C)cc1 ; CC(C)(C)c1ccc(N2c3c(sc4ccc(C(C)(C)C)cc34)B3c4c(cc5c(oc6ccccc65)c42)-c2cc4c(cc2N3c2ccc(-c3ccccc3)cc2)oc2cc3c(cc24)C(C)(C)CCC3(C)C)cc1] 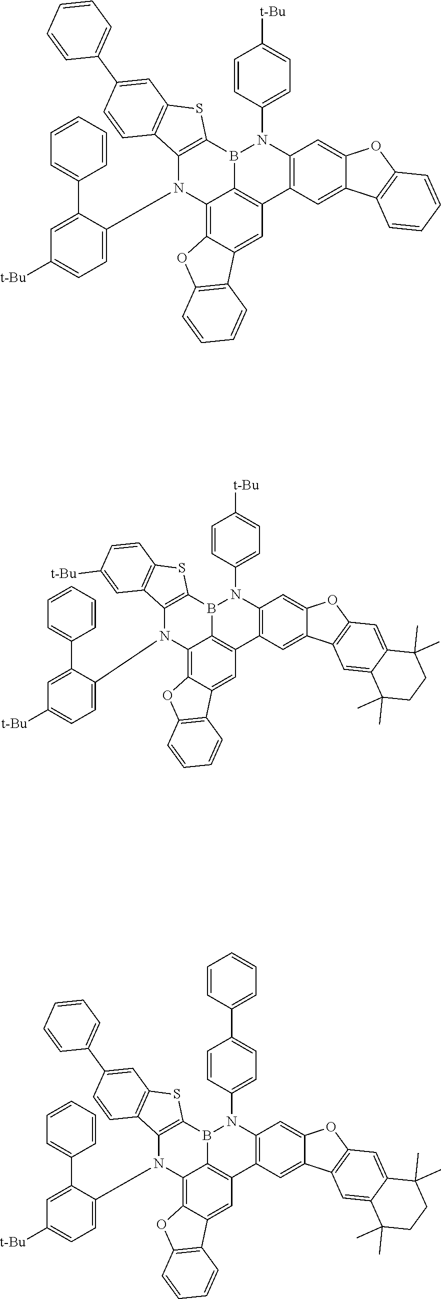 [SMILES: CC(C)(C)c1ccc(N2B3c4sc5cc(-c6ccccc6)ccc5c4N(c4ccc(C(C)(C)C)cc4-c4ccccc4)c4c3c(cc3c4oc4ccccc43)-c3cc4c(cc32)oc2ccccc24)cc1 ; CC(C)(C)c1ccc(N2B3c4sc5ccc(C(C)(C)C)cc5c4N(c4ccc(C(C)(C)C)cc4-c4ccccc4)c4c3c(cc3c4oc4ccccc43)-c3cc4c(cc32)oc2cc3c(cc24)C(C)(C)CCC3(C)C)cc1 ; CC(C)(C)c1ccc(N2c3c(sc4cc(-c5ccccc5)ccc34)B3c4c(cc5c(oc6ccccc65)c42)-c2cc4c(cc2N3c2ccc(-c3ccccc3)cc2)oc2cc3c(cc24)C(C)(C)CCC3(C)C)c(-c2ccccc2)c1] 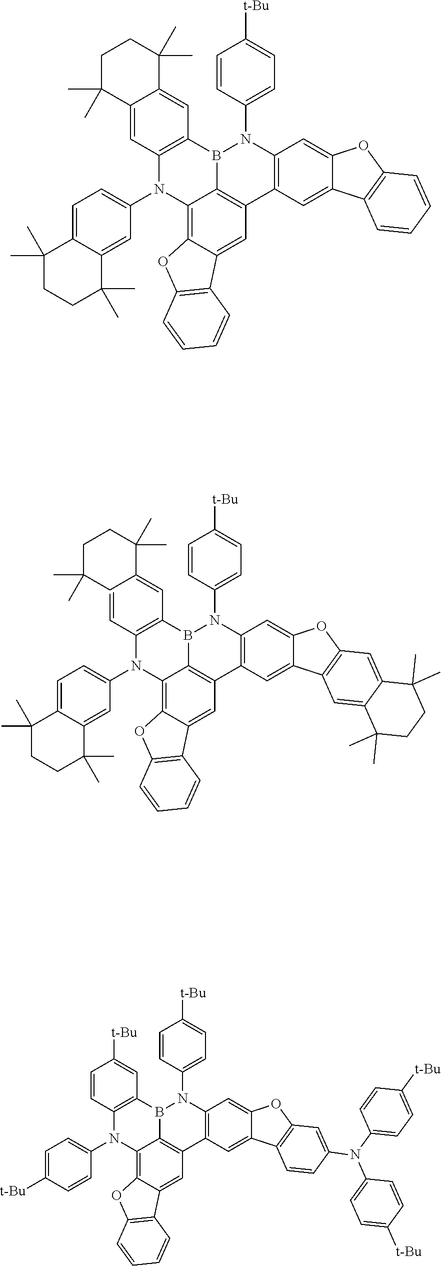 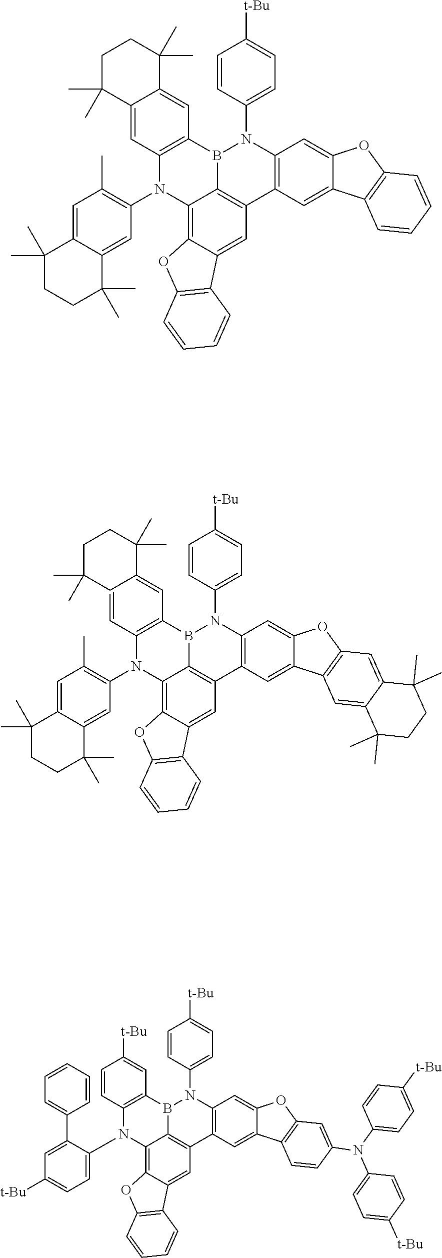 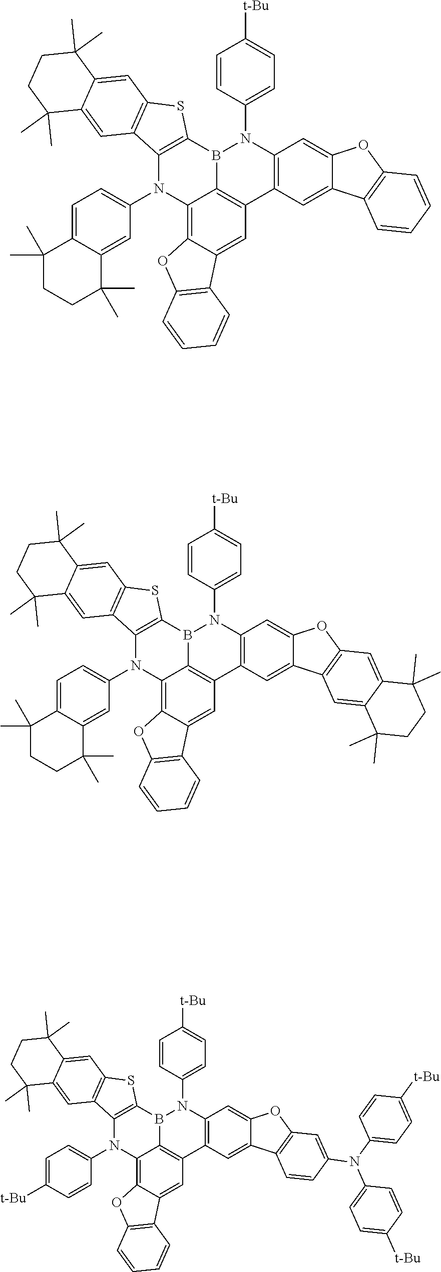 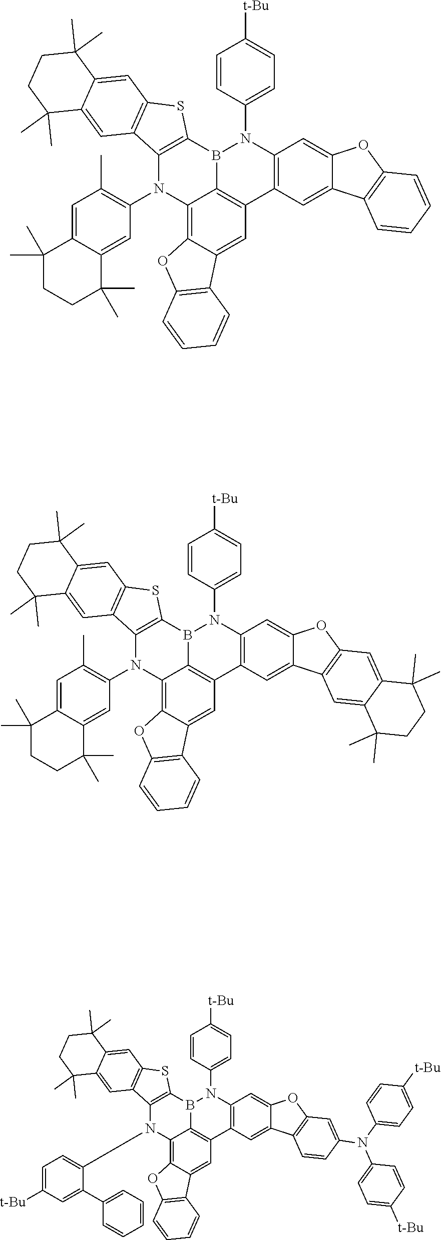 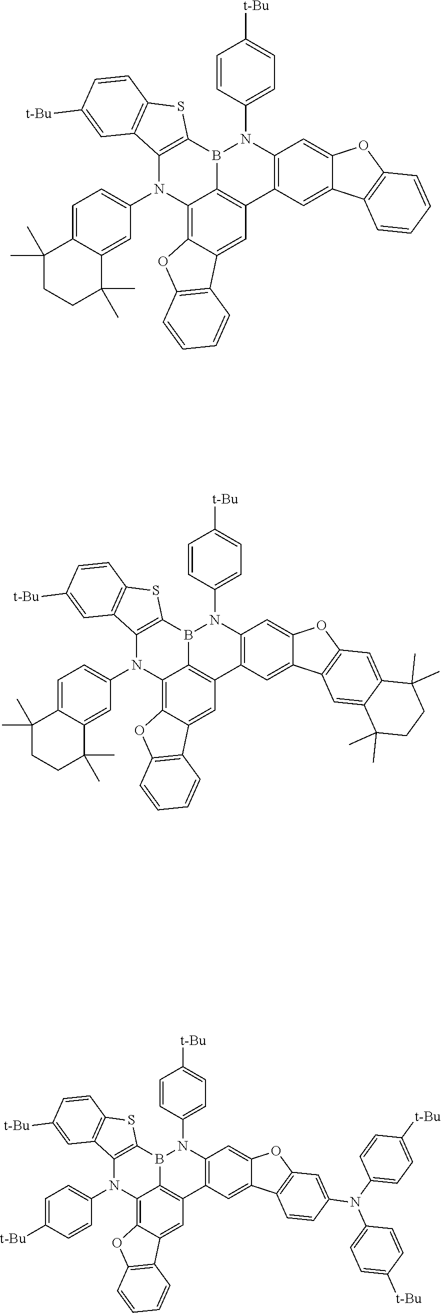 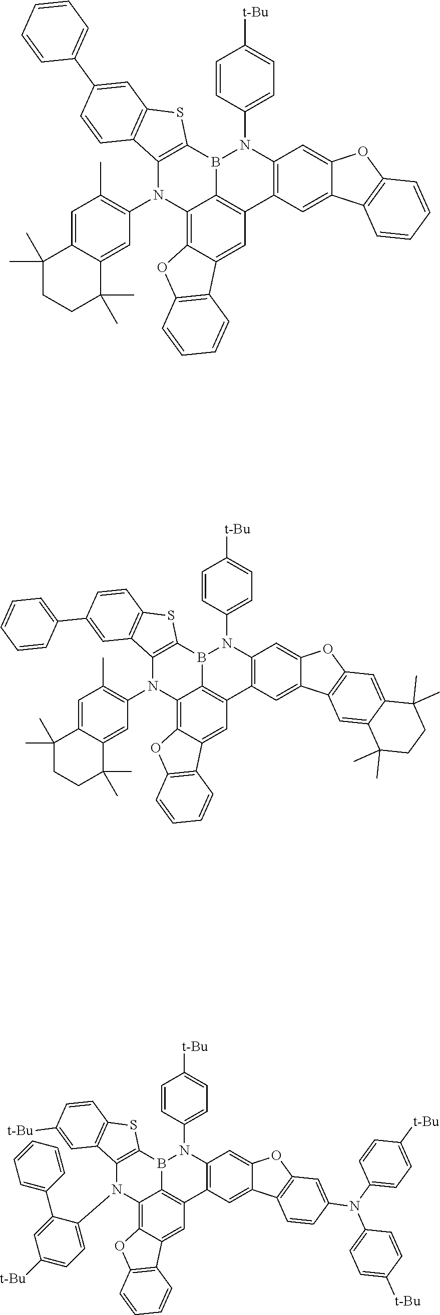 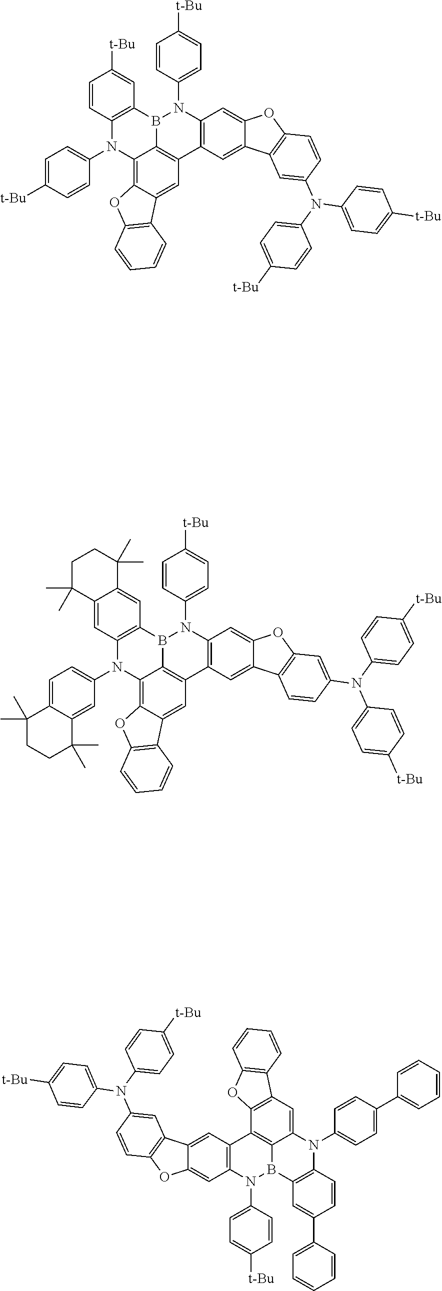 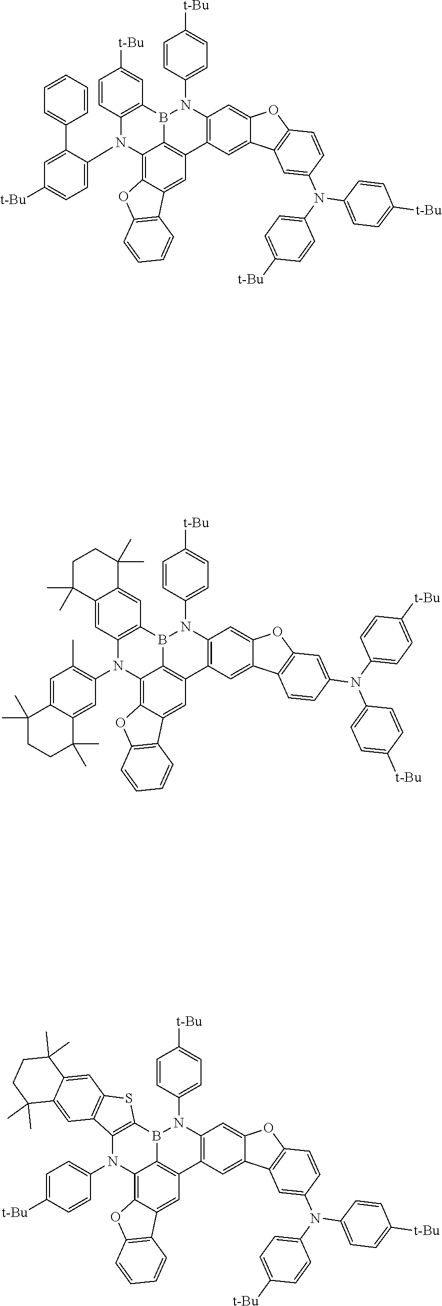 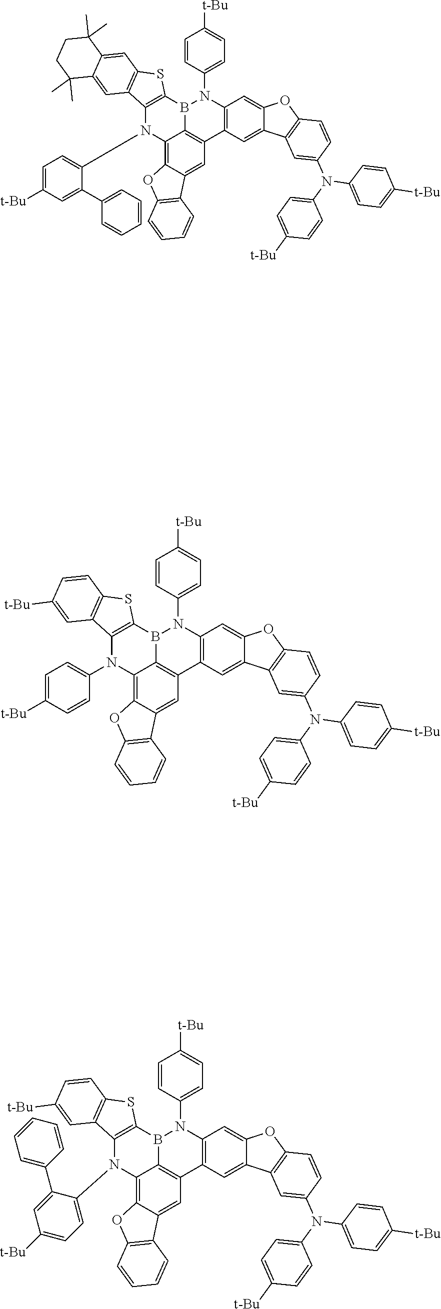 [SMILES: CC(C)(C)Cc1cccc(N2c3c(sc4cc5c(cc34)C(C)(C)CCC5(C)C)B3c4c(cc5c(oc6ccccc65)c42)-c2cc4c(cc2N3c2ccc(C(C)(C)C)cc2)oc2ccc(N(c3ccc(C(C)(C)C)cc3)c3ccc(C(C)(C)C)cc3)cc24)c1-c1ccccc1 ; CC(C)(C)Cc1cccc(N2c3c(sc4ccc(C(C)(C)C)cc34)B3c4c(cc5c(oc6ccccc65)c42)-c2cc4c(cc2N3c2ccc(C(C)(C)C)cc2)oc2ccc(N(c3ccc(C(C)(C)C)cc3)c3ccc(C(C)(C)C)cc3)cc24)c1 ; CC(C)(C)c1ccc(N2B3c4sc5ccc(C(C)(C)C)cc5c4N(c4ccc(C(C)(C)C)cc4-c4ccccc4)c4c3c(cc3c4oc4ccccc43)-c3cc4c(cc32)oc2ccc(N(c3ccc(C(C)(C)C)cc3)c3ccc(C(C)(C)C)cc3)cc24)cc1] 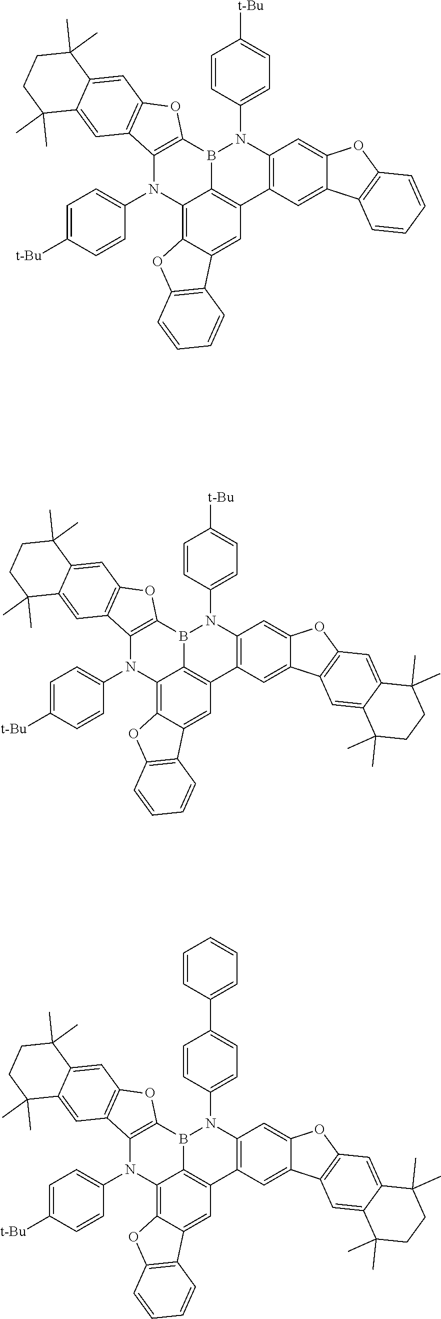 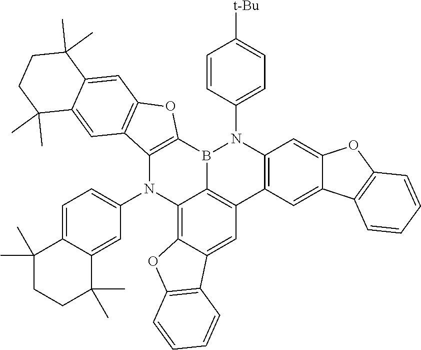 [SMILES: CC(C)(C)c1ccc(N2B3c4oc5cc6c(cc5c4N(c4ccc5c(c4)C(C)(C)CCC5(C)C)c4c3c(cc3c4oc4ccccc43)-c3cc4c(cc32)oc2ccccc24)C(C)(C)CCC6(C)C)cc1] 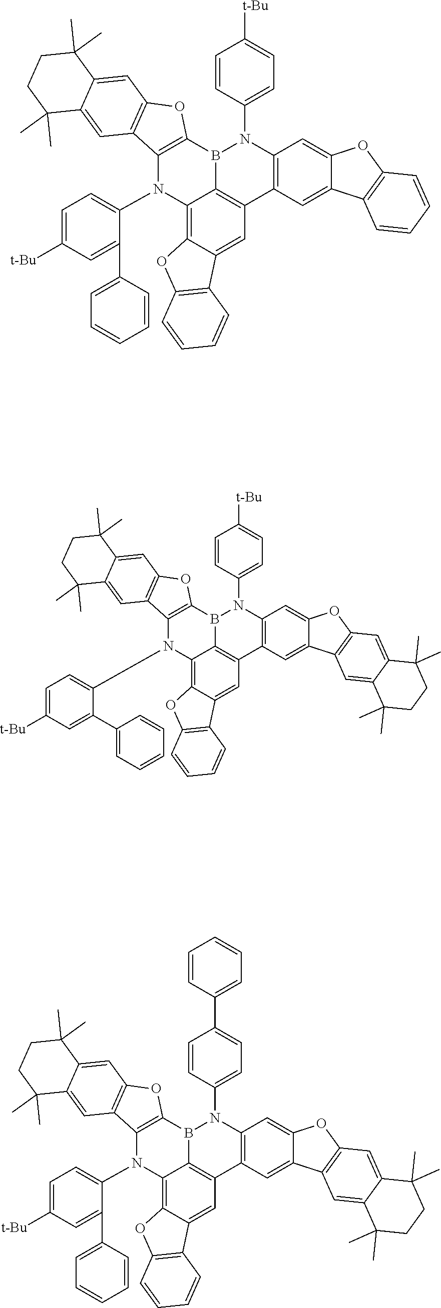 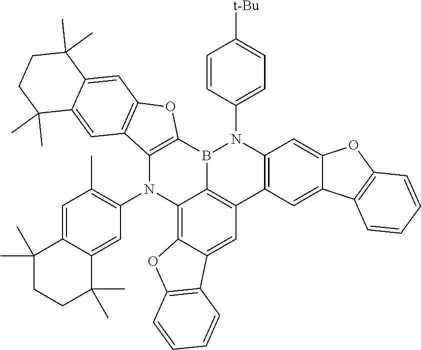 [SMILES: Cc1cc2c(cc1N1c3c(oc4cc5c(cc34)C(C)(C)CCC5(C)C)B3c4c(cc5c(oc6ccccc65)c41)-c1cc4c(cc1N3c1ccc(C(C)(C)C)cc1)oc1ccccc14)C(C)(C)CCC2(C)C] 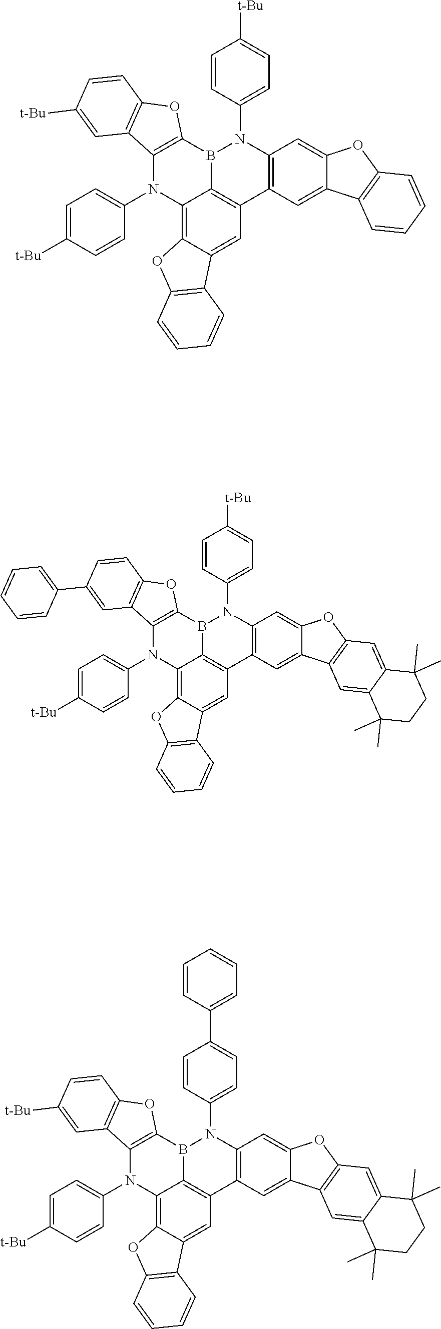 [SMILES: CC(C)(C)c1ccc(N2B3c4oc5ccc(C(C)(C)C)cc5c4N(c4ccc(C(C)(C)C)cc4)c4c3c(cc3c4oc4ccccc43)-c3cc4c(cc32)oc2ccccc24)cc1 ; CC(C)(C)c1ccc(N2B3c4oc5ccc(-c6ccccc6)cc5c4N(c4ccc(C(C)(C)C)cc4)c4c3c(cc3c4oc4ccccc43)-c3cc4c(cc32)oc2cc3c(cc24)C(C)(C)CCC3(C)C)cc1 ; CC(C)(C)c1ccc(N2c3c(oc4ccc(C(C)(C)C)cc34)B3c4c(cc5c(oc6ccccc65)c42)-c2cc4c(cc2N3c2ccc(-c3ccccc3)cc2)oc2cc3c(cc24)C(C)(C)CCC3(C)C)cc1] 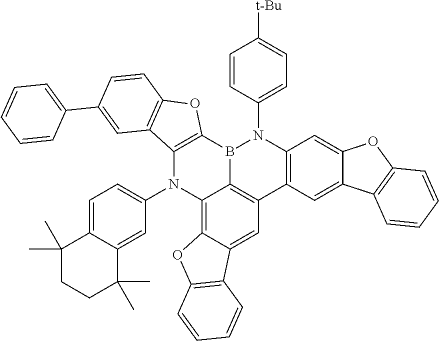 [SMILES: CC(C)(C)c1ccc(N2B3c4oc5ccc(-c6ccccc6)cc5c4N(c4ccc5c(c4)C(C)(C)CCC5(C)C)c4c3c(cc3c4oc4ccccc43)-c3cc4c(cc32)oc2ccccc24)cc1] 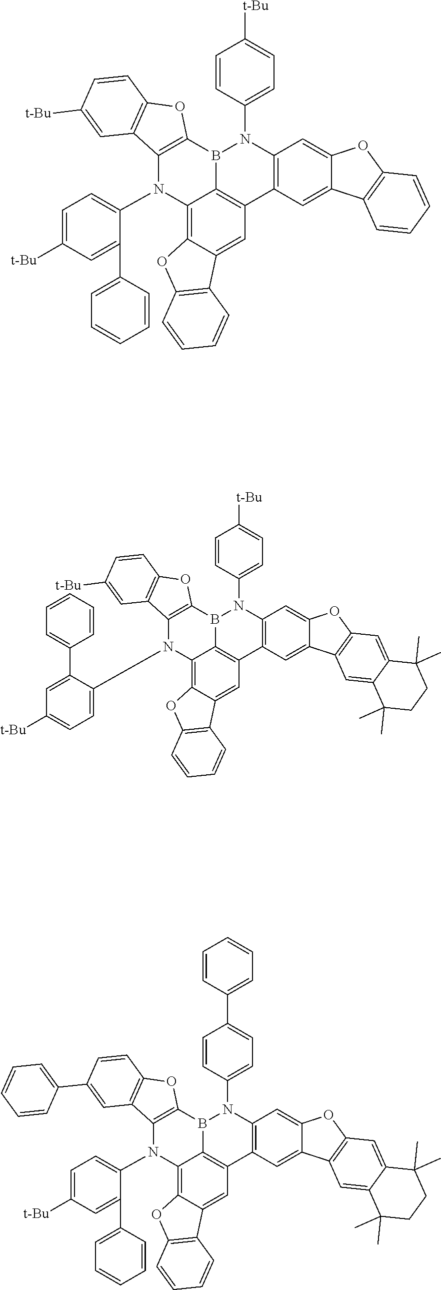 [SMILES: CC(C)(C)c1ccc(N2B3c4oc5ccc(C(C)(C)C)cc5c4N(c4ccc(C(C)(C)C)cc4-c4ccccc4)c4c3c(cc3c4oc4ccccc43)-c3cc4c(cc32)oc2ccccc24)cc1 ; CC(C)(C)c1ccc(N2B3c4oc5ccc(C(C)(C)C)cc5c4N(c4ccc(C(C)(C)C)cc4-c4ccccc4)c4c3c(cc3c4oc4ccccc43)-c3cc4c(cc32)oc2cc3c(cc24)C(C)(C)CCC3(C)C)cc1 ; CC(C)(C)c1ccc(N2c3c(oc4ccc(-c5ccccc5)cc34)B3c4c(cc5c(oc6ccccc65)c42)-c2cc4c(cc2N3c2ccc(-c3ccccc3)cc2)oc2cc3c(cc24)C(C)(C)CCC3(C)C)c(-c2ccccc2)c1] 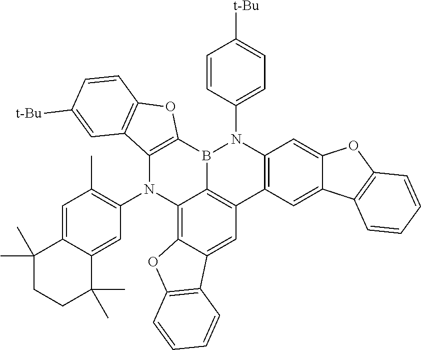 [SMILES: Cc1cc2c(cc1N1c3c(oc4ccc(C(C)(C)C)cc34)B3c4c(cc5c(oc6ccccc65)c41)-c1cc4c(cc1N3c1ccc(C(C)(C)C)cc1)oc1ccccc14)C(C)(C)CCC2(C)C] 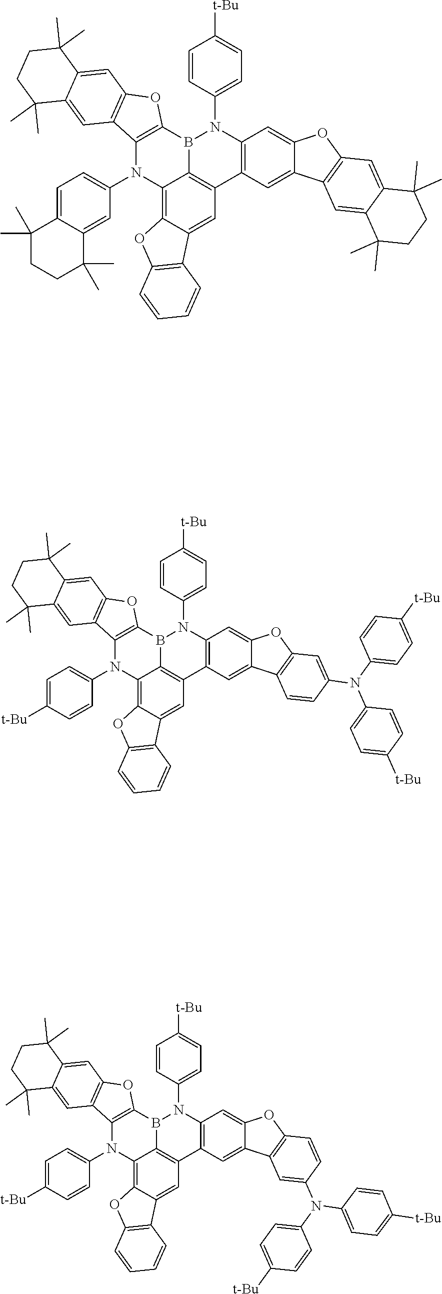 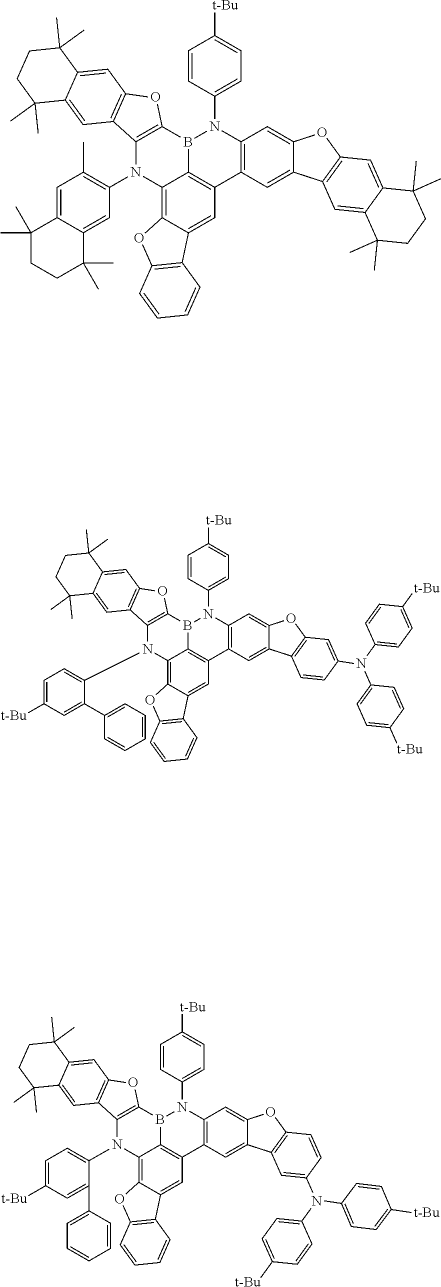 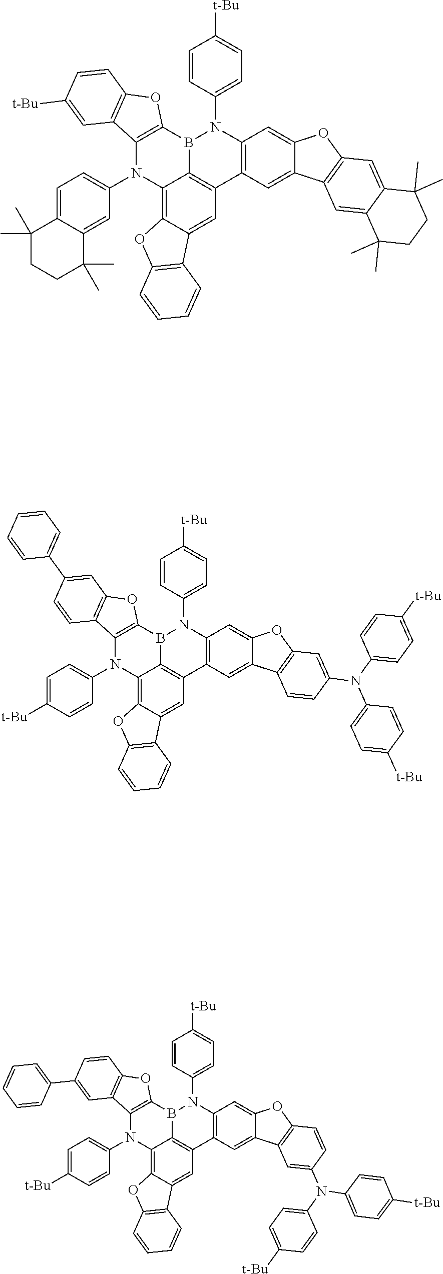 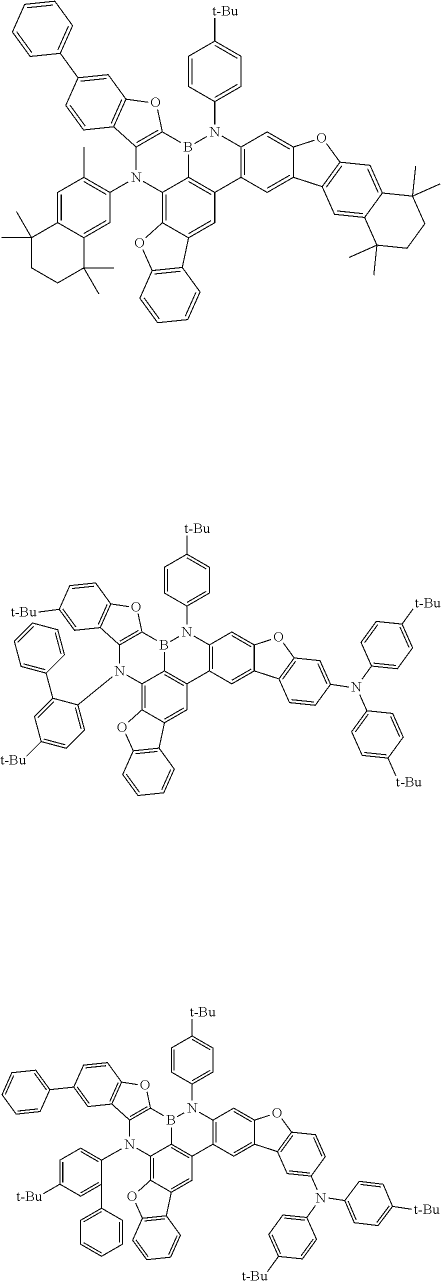 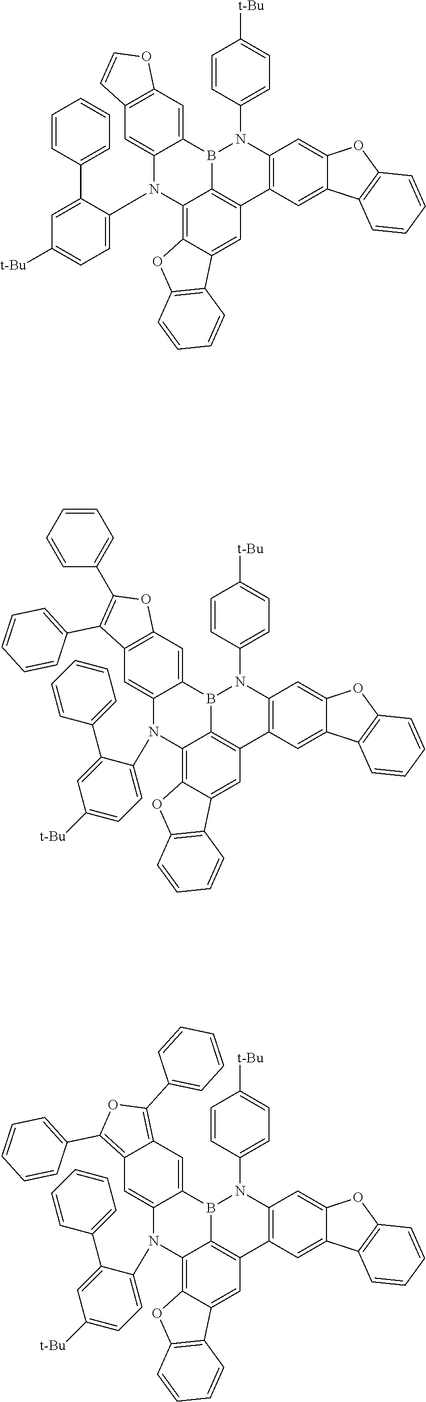 [SMILES: CC(C)(C)c1ccc(N2B3c4cc5occc5cc4N(c4ccc(C(C)(C)C)cc4-c4ccccc4)c4c3c(cc3c4oc4ccccc43)-c3cc4c(cc32)oc2ccccc24)cc1 ; CC(C)(C)c1ccc(N2B3c4cc5oc(-c6ccccc6)c(-c6ccccc6)c5cc4N(c4ccc(C(C)(C)C)cc4-c4ccccc4)c4c3c(cc3c4oc4ccccc43)-c3cc4c(cc32)oc2ccccc24)cc1 ; CC(C)(C)c1ccc(N2B3c4cc5c(-c6ccccc6)oc(-c6ccccc6)c5cc4N(c4ccc(C(C)(C)C)cc4-c4ccccc4)c4c3c(cc3c4oc4ccccc43)-c3cc4c(cc32)oc2ccccc24)cc1] 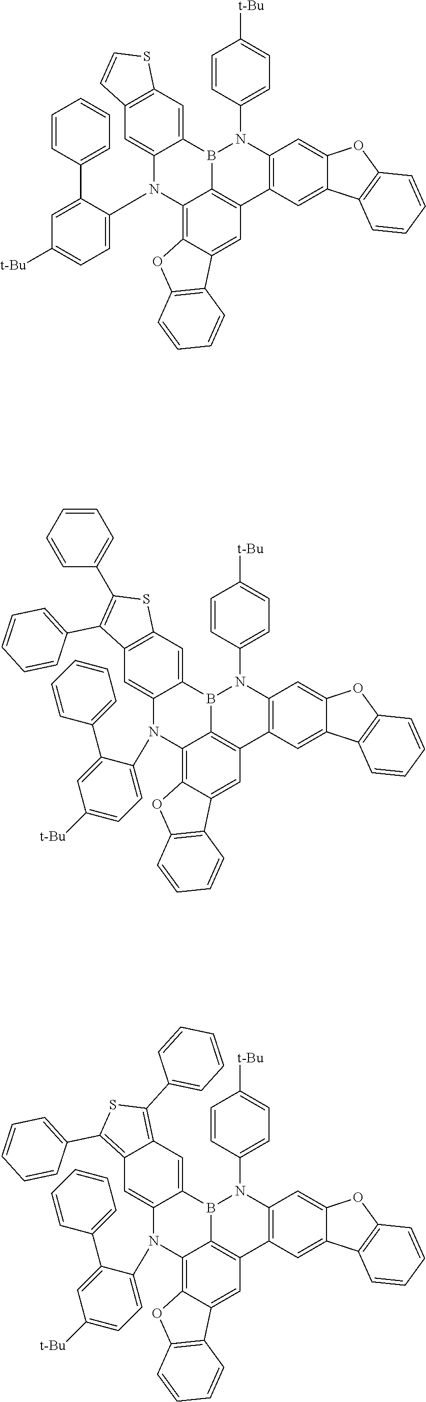 [SMILES: CC(C)(C)c1ccc(N2B3c4cc5sccc5cc4N(c4ccc(C(C)(C)C)cc4-c4ccccc4)c4c3c(cc3c4oc4ccccc43)-c3cc4c(cc32)oc2ccccc24)cc1 ; CC(C)(C)c1ccc(N2B3c4cc5sc(-c6ccccc6)c(-c6ccccc6)c5cc4N(c4ccc(C(C)(C)C)cc4-c4ccccc4)c4c3c(cc3c4oc4ccccc43)-c3cc4c(cc32)oc2ccccc24)cc1 ; CC(C)(C)c1ccc(N2B3c4cc5c(-c6ccccc6)sc(-c6ccccc6)c5cc4N(c4ccc(C(C)(C)C)cc4-c4ccccc4)c4c3c(cc3c4oc4ccccc43)-c3cc4c(cc32)oc2ccccc24)cc1] 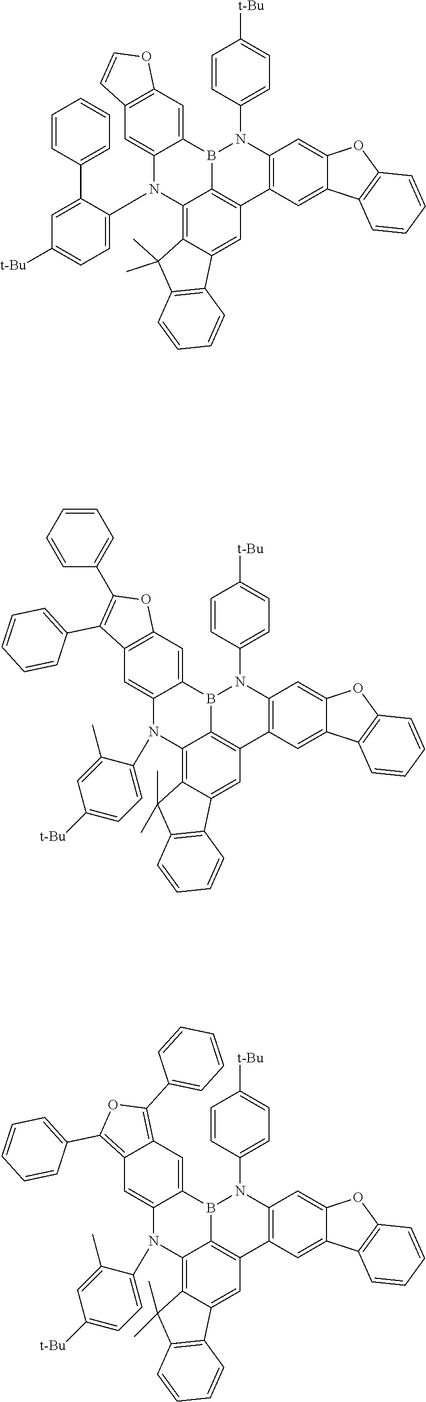 [SMILES: CC(C)(C)c1ccc(N2B3c4cc5occc5cc4N(c4ccc(C(C)(C)C)cc4-c4ccccc4)c4c3c(cc3c4C(C)(C)c4ccccc4-3)-c3cc4c(cc32)oc2ccccc24)cc1 ; Cc1cc(C(C)(C)C)ccc1N1c2cc3c(-c4ccccc4)c(-c4ccccc4)oc3cc2B2c3c(cc4c(c31)C(C)(C)c1ccccc1-4)-c1cc3c(cc1N2c1ccc(C(C)(C)C)cc1)oc1ccccc13 ; Cc1cc(C(C)(C)C)ccc1N1c2cc3c(-c4ccccc4)oc(-c4ccccc4)c3cc2B2c3c(cc4c(c31)C(C)(C)c1ccccc1-4)-c1cc3c(cc1N2c1ccc(C(C)(C)C)cc1)oc1ccccc13] 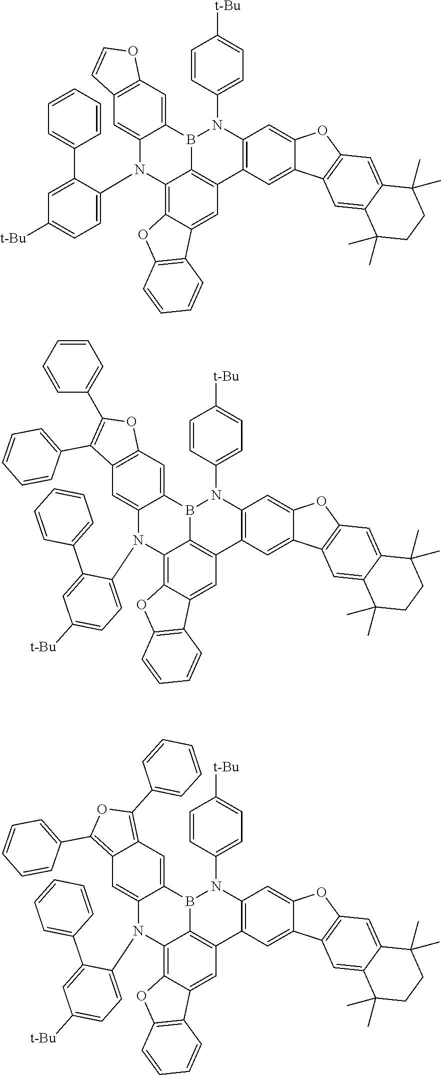 [SMILES: CC(C)(C)c1ccc(N2B3c4cc5occc5cc4N(c4ccc(C(C)(C)C)cc4-c4ccccc4)c4c3c(cc3c4oc4ccccc43)-c3cc4c(cc32)oc2cc3c(cc24)C(C)(C)CCC3(C)C)cc1 ; CC(C)(C)c1ccc(N2B3c4cc5oc(-c6ccccc6)c(-c6ccccc6)c5cc4N(c4ccc(C(C)(C)C)cc4-c4ccccc4)c4c3c(cc3c4oc4ccccc43)-c3cc4c(cc32)oc2cc3c(cc24)C(C)(C)CCC3(C)C)cc1 ; CC(C)(C)c1ccc(N2B3c4cc5c(-c6ccccc6)oc(-c6ccccc6)c5cc4N(c4ccc(C(C)(C)C)cc4-c4ccccc4)c4c3c(cc3c4oc4ccccc43)-c3cc4c(cc32)oc2cc3c(cc24)C(C)(C)CCC3(C)C)cc1] 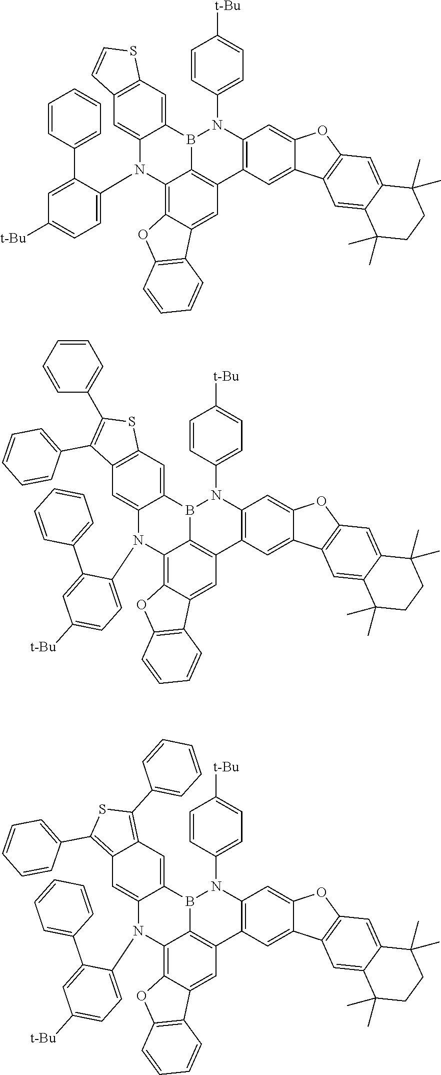 [SMILES: CC(C)(C)c1ccc(N2B3c4cc5sccc5cc4N(c4ccc(C(C)(C)C)cc4-c4ccccc4)c4c3c(cc3c4oc4ccccc43)-c3cc4c(cc32)oc2cc3c(cc24)C(C)(C)CCC3(C)C)cc1 ; CC(C)(C)c1ccc(N2B3c4cc5sc(-c6ccccc6)c(-c6ccccc6)c5cc4N(c4ccc(C(C)(C)C)cc4-c4ccccc4)c4c3c(cc3c4oc4ccccc43)-c3cc4c(cc32)oc2cc3c(cc24)C(C)(C)CCC3(C)C)cc1 ; CC(C)(C)c1ccc(N2B3c4cc5c(-c6ccccc6)sc(-c6ccccc6)c5cc4N(c4ccc(C(C)(C)C)cc4-c4ccccc4)c4c3c(cc3c4oc4ccccc43)-c3cc4c(cc32)oc2cc3c(cc24)C(C)(C)CCC3(C)C)cc1] 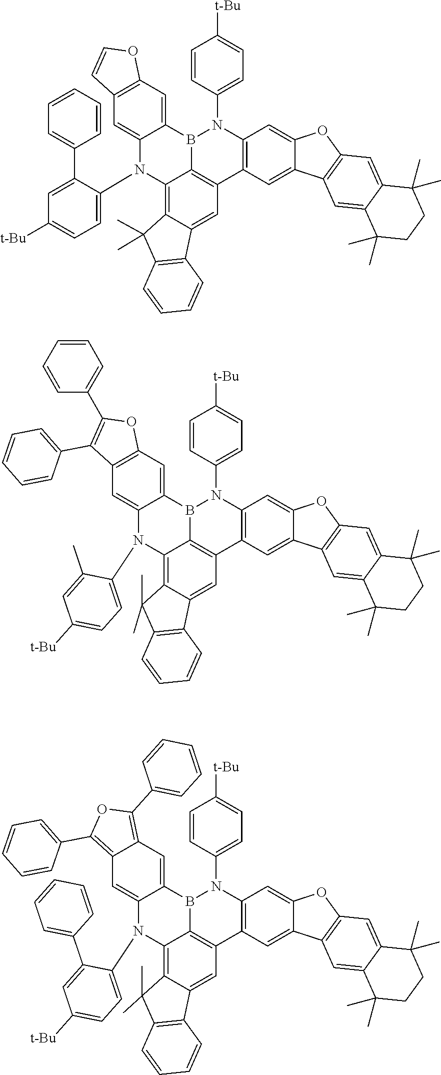 [SMILES: CC(C)(C)c1ccc(N2B3c4cc5occc5cc4N(c4ccc(C(C)(C)C)cc4-c4ccccc4)c4c3c(cc3c4C(C)(C)c4ccccc4-3)-c3cc4c(cc32)oc2cc3c(cc24)C(C)(C)CCC3(C)C)cc1 ; Cc1cc(C(C)(C)C)ccc1N1c2cc3c(-c4ccccc4)c(-c4ccccc4)oc3cc2B2c3c(cc4c(c31)C(C)(C)c1ccccc1-4)-c1cc3c(cc1N2c1ccc(C(C)(C)C)cc1)oc1cc2c(cc13)C(C)(C)CCC2(C)C ; CC(C)(C)c1ccc(N2B3c4cc5c(-c6ccccc6)oc(-c6ccccc6)c5cc4N(c4ccc(C(C)(C)C)cc4-c4ccccc4)c4c3c(cc3c4C(C)(C)c4ccccc4-3)-c3cc4c(cc32)oc2cc3c(cc24)C(C)(C)CCC3(C)C)cc1] 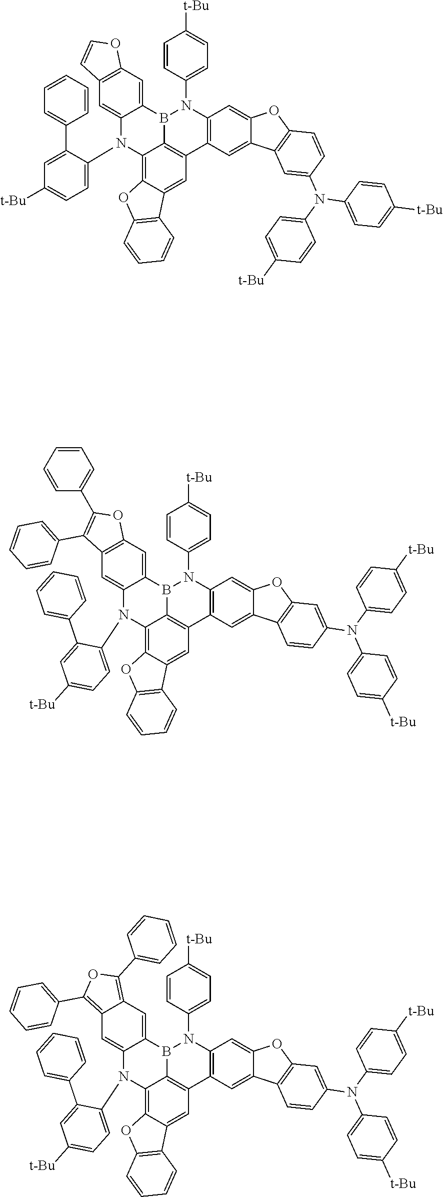 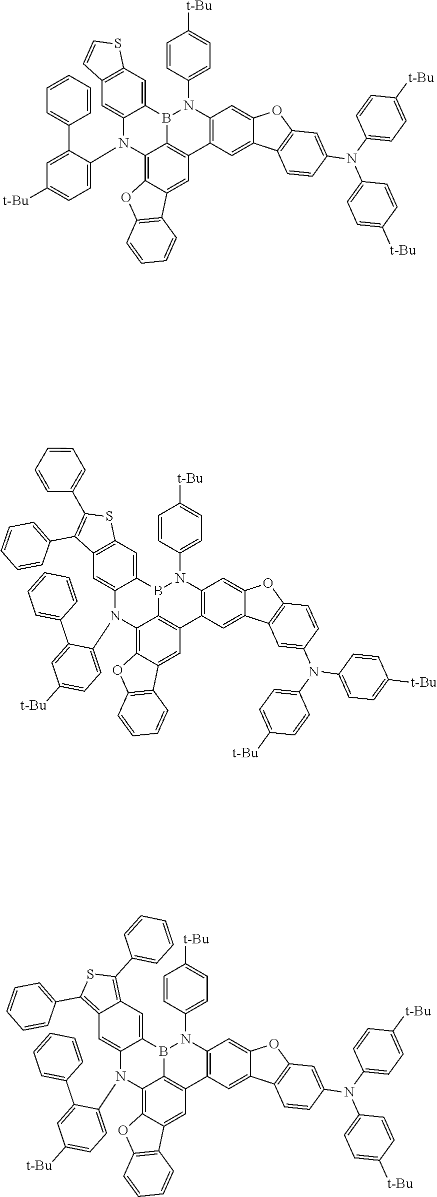 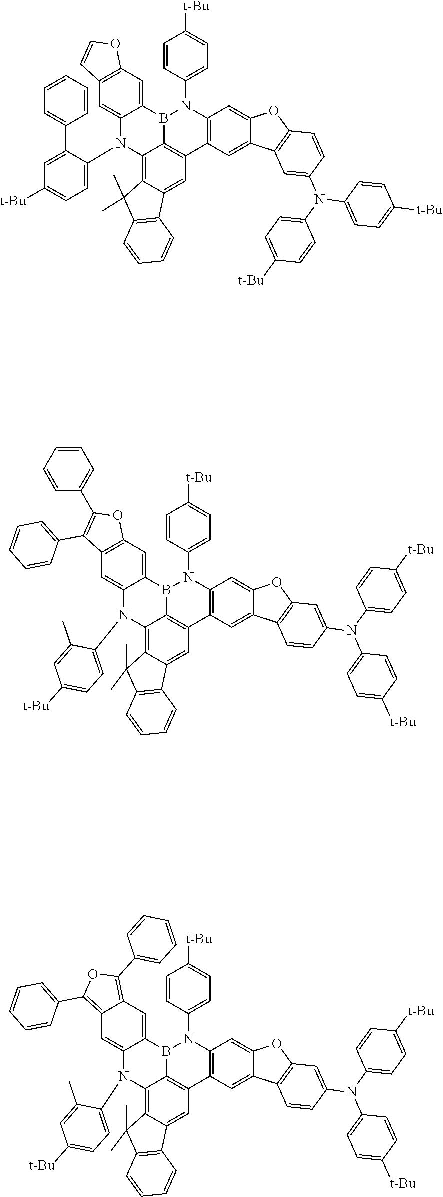 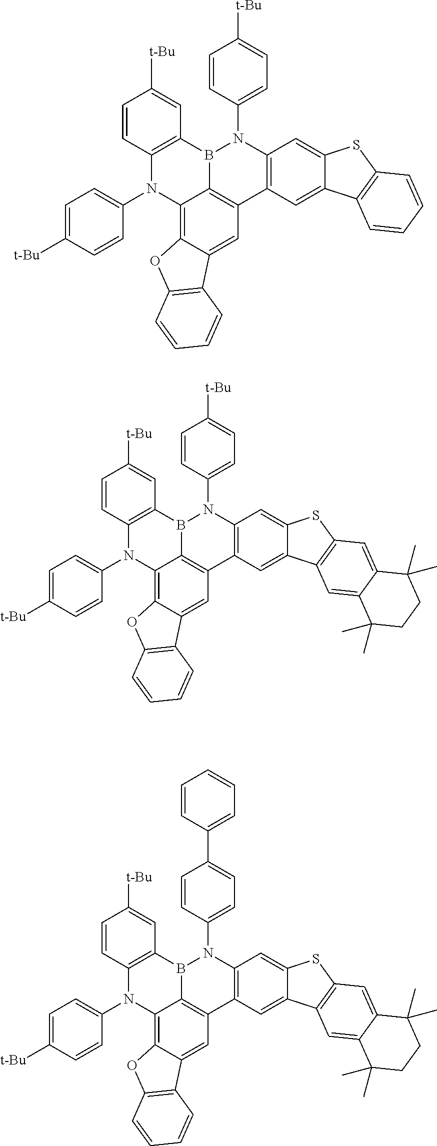 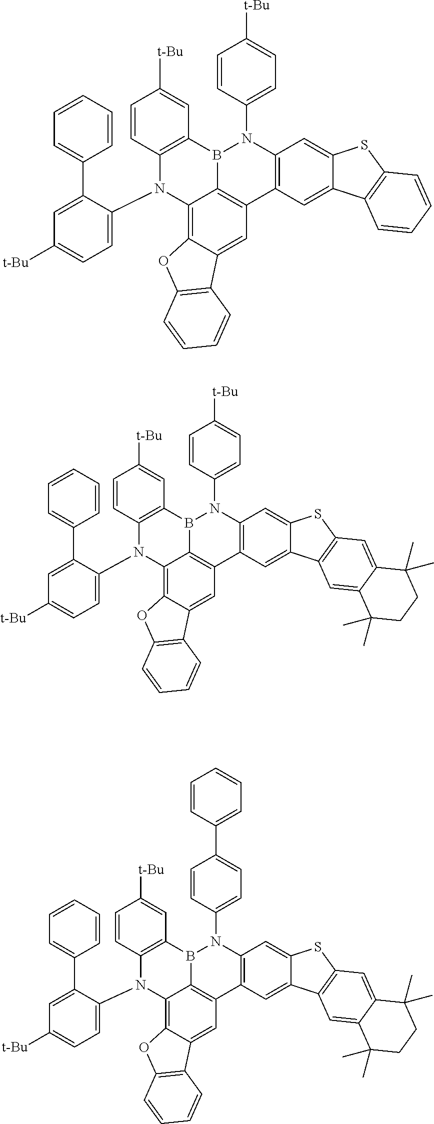 [SMILES: CC(C)(C)c1ccc(N2B3c4cc(C(C)(C)C)ccc4N(c4ccc(C(C)(C)C)cc4-c4ccccc4)c4c3c(cc3c4oc4ccccc43)-c3cc4c(cc32)sc2ccccc24)cc1 ; CC(C)(C)c1ccc(N2B3c4cc(C(C)(C)C)ccc4N(c4ccc(C(C)(C)C)cc4-c4ccccc4)c4c3c(cc3c4oc4ccccc43)-c3cc4c(cc32)sc2cc3c(cc24)C(C)(C)CCC3(C)C)cc1 ; CC(C)(C)c1ccc2c(c1)B1c3c(cc4c(oc5ccccc54)c3N2c2ccc(C(C)(C)C)cc2-c2ccccc2)-c2cc3c(cc2N1c1ccc(-c2ccccc2)cc1)sc1cc2c(cc13)C(C)(C)CCC2(C)C] 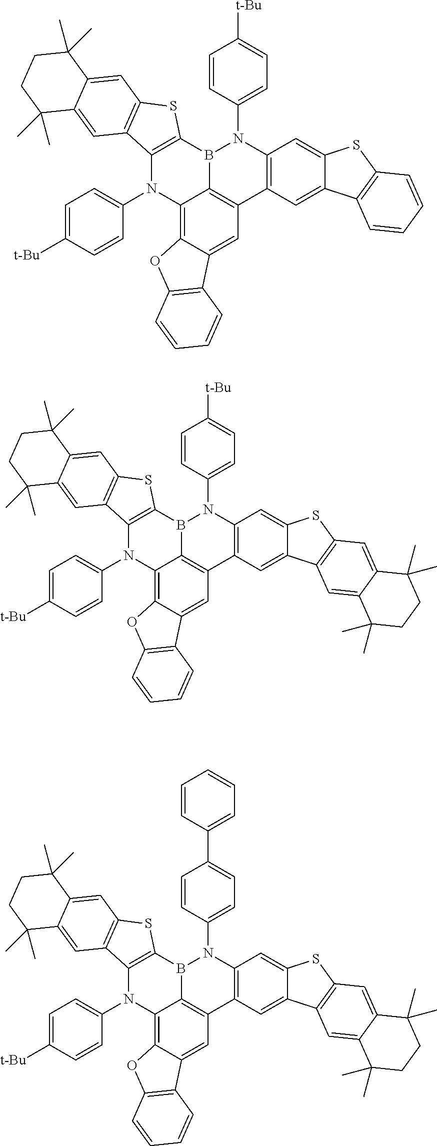 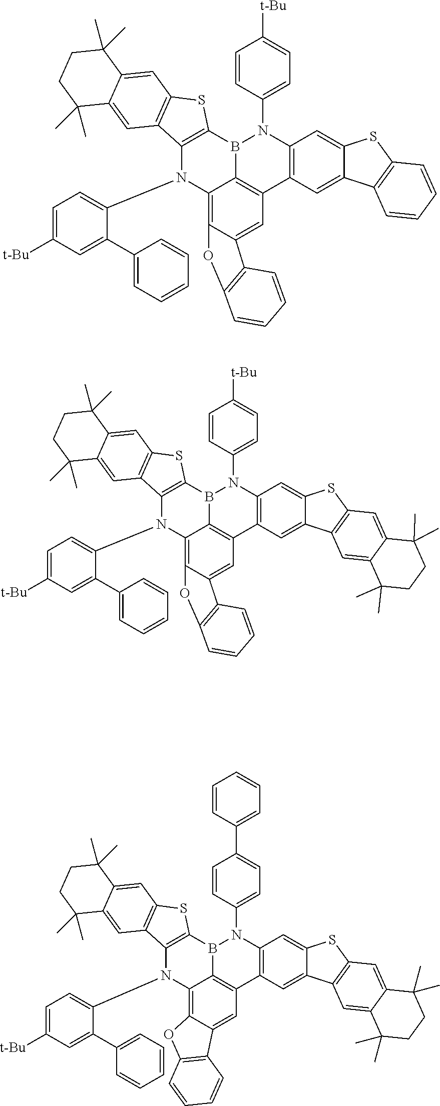 [SMILES: CC(C)(C)c1ccc(N2B3c4sc5cc6c(cc5c4N(c4ccc(C(C)(C)C)cc4-c4ccccc4)c4c3c(cc3c4oc4ccccc43)-c3cc4c(cc32)sc2ccccc24)C(C)(C)CCC6(C)C)cc1 ; CC(C)(C)c1ccc(N2B3c4sc5cc6c(cc5c4N(c4ccc(C(C)(C)C)cc4-c4ccccc4)c4c3c(cc3c4oc4ccccc43)-c3cc4c(cc32)sc2cc3c(cc24)C(C)(C)CCC3(C)C)C(C)(C)CCC6(C)C)cc1 ; CC(C)(C)c1ccc(N2c3c(sc4cc5c(cc34)C(C)(C)CCC5(C)C)B3c4c(cc5c(oc6ccccc65)c42)-c2cc4c(cc2N3c2ccc(-c3ccccc3)cc2)sc2cc3c(cc24)C(C)(C)CCC3(C)C)c(-c2ccccc2)c1] 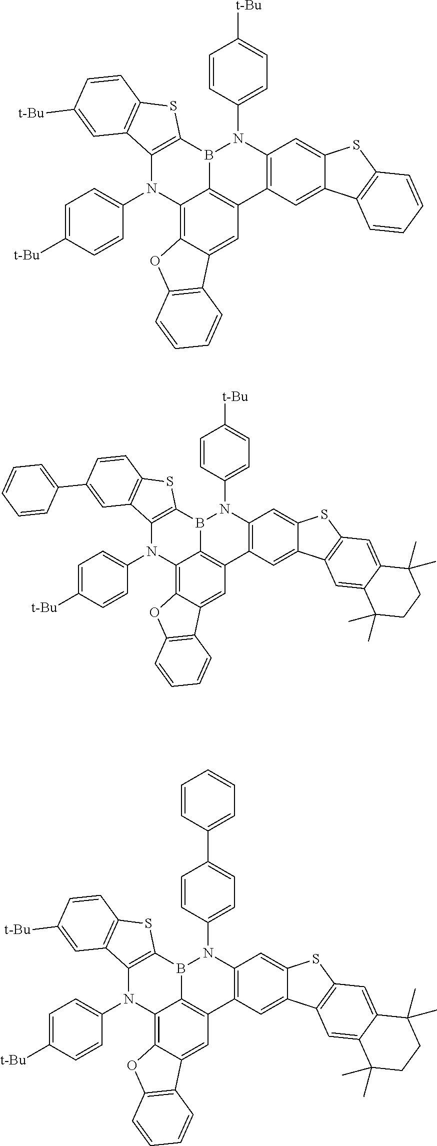 [SMILES: CC(C)(C)c1ccc(N2B3c4sc5ccc(C(C)(C)C)cc5c4N(c4ccc(C(C)(C)C)cc4)c4c3c(cc3c4oc4ccccc43)-c3cc4c(cc32)sc2ccccc24)cc1 ; CC(C)(C)c1ccc(N2B3c4sc5ccc(-c6ccccc6)cc5c4N(c4ccc(C(C)(C)C)cc4)c4c3c(cc3c4oc4ccccc43)-c3cc4c(cc32)sc2cc3c(cc24)C(C)(C)CCC3(C)C)cc1 ; CC(C)(C)c1ccc(N2c3c(sc4ccc(C(C)(C)C)cc34)B3c4c(cc5c(oc6ccccc65)c42)-c2cc4c(cc2N3c2ccc(-c3ccccc3)cc2)sc2cc3c(cc24)C(C)(C)CCC3(C)C)cc1] 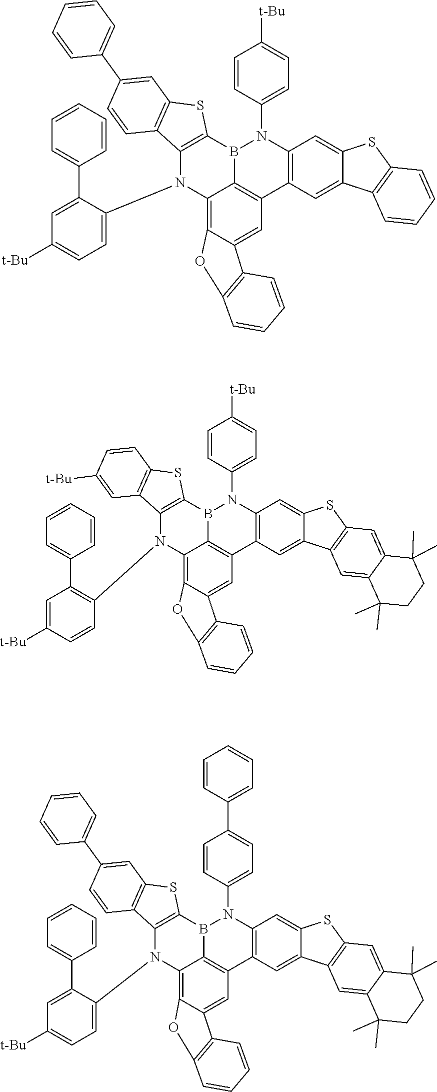 [SMILES: CC(C)(C)c1ccc(N2B3c4sc5cc(-c6ccccc6)ccc5c4N(c4ccc(C(C)(C)C)cc4-c4ccccc4)c4c3c(cc3c4oc4ccccc43)-c3cc4c(cc32)sc2ccccc24)cc1 ; CC(C)(C)c1ccc(N2B3c4sc5ccc(C(C)(C)C)cc5c4N(c4ccc(C(C)(C)C)cc4-c4ccccc4)c4c3c(cc3c4oc4ccccc43)-c3cc4c(cc32)sc2cc3c(cc24)C(C)(C)CCC3(C)C)cc1 ; CC(C)(C)c1ccc(N2c3c(sc4cc(-c5ccccc5)ccc34)B3c4c(cc5c(oc6ccccc65)c42)-c2cc4c(cc2N3c2ccc(-c3ccccc3)cc2)sc2cc3c(cc24)C(C)(C)CCC3(C)C)c(-c2ccccc2)c1] 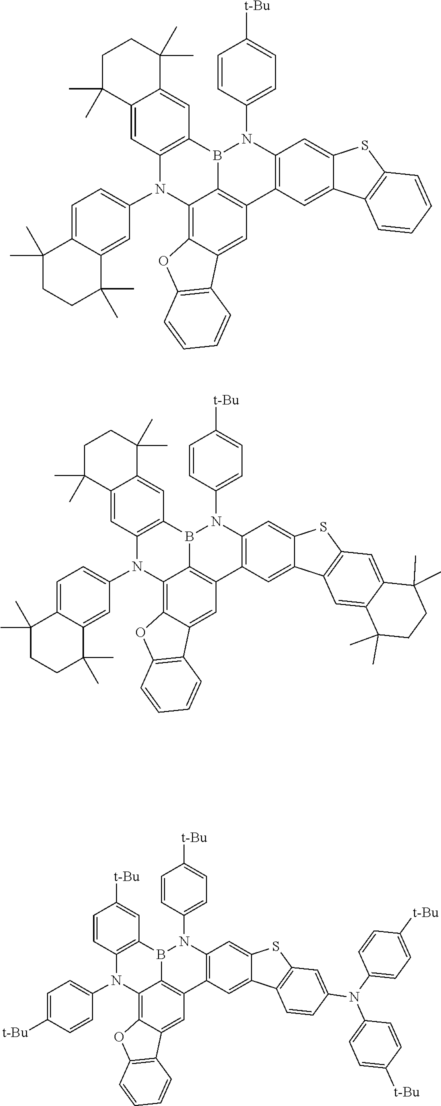 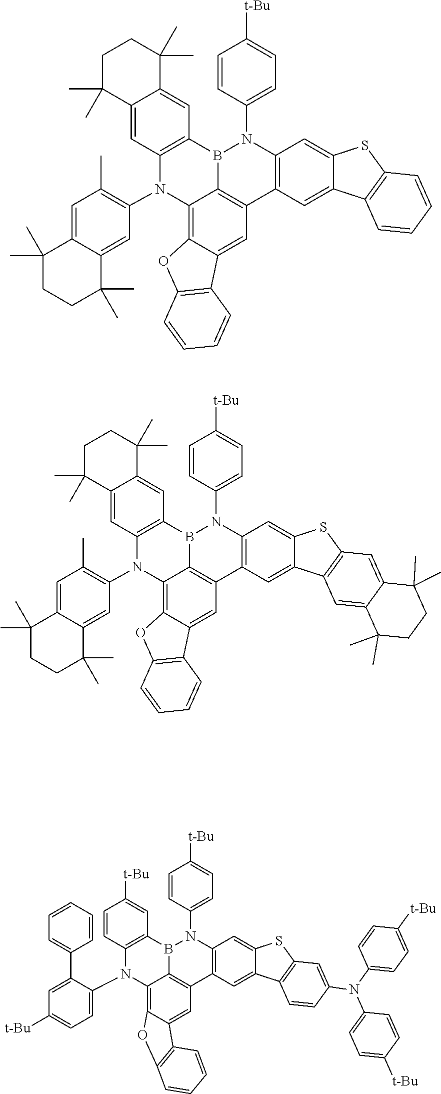 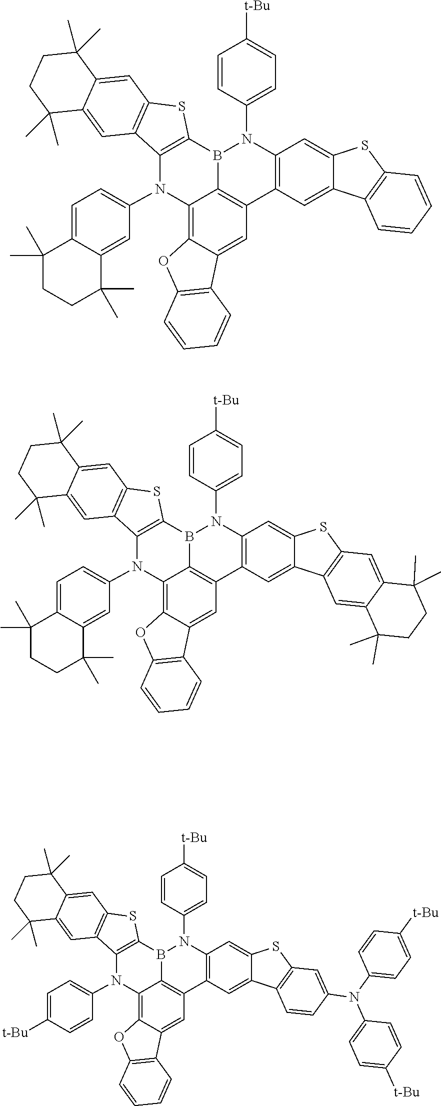 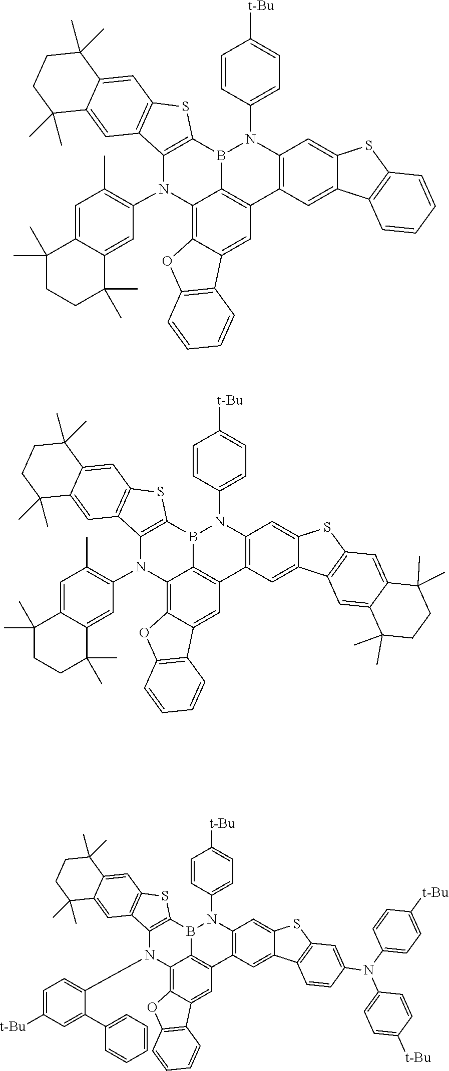 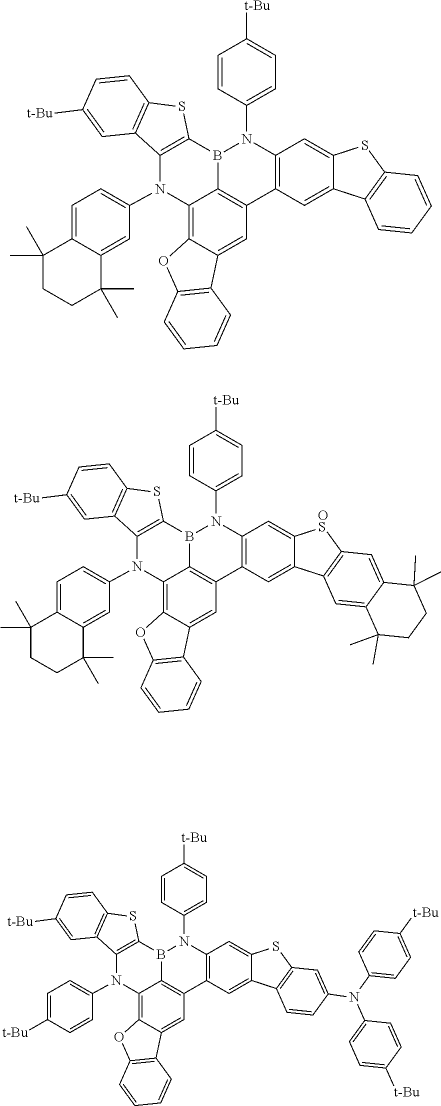 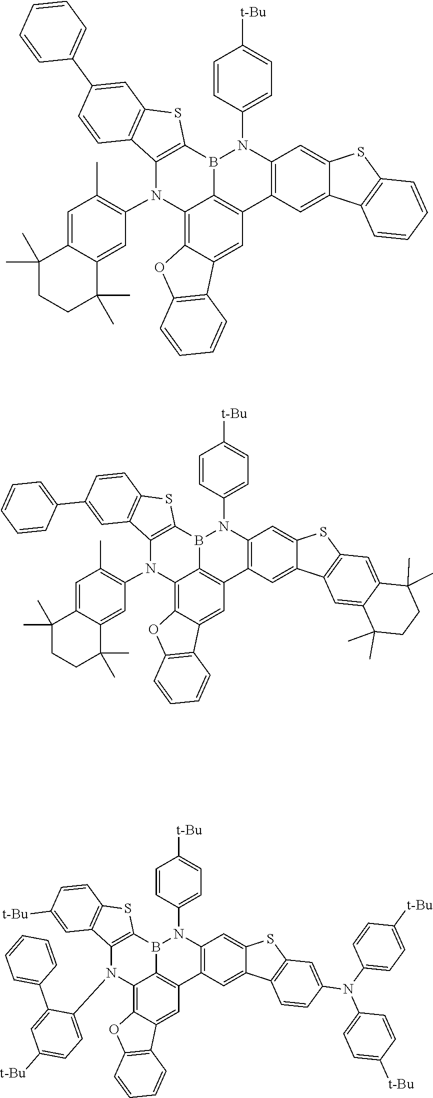 [SMILES: Cc1cc2c(cc1N1c3c(sc4cc(-c5ccccc5)ccc34)B3c4c(cc5c(oc6ccccc65)c41)-c1cc4c(cc1N3c1ccc(C(C)(C)C)cc1)sc1ccccc14)C(C)(C)CCC2(C)C ; Cc1cc2c(cc1N1c3c(sc4ccc(-c5ccccc5)cc34)B3c4c(cc5c(oc6ccccc65)c41)-c1cc4c(cc1N3c1ccc(C(C)(C)C)cc1)sc1cc3c(cc14)C(C)(C)CCC3(C)C)C(C)(C)CCC2(C)C ; CC(C)(C)c1ccc(N2B3c4sc5ccc(C(C)(C)C)cc5c4N(c4ccc(C(C)(C)C)cc4-c4ccccc4)c4c3c(cc3c4oc4ccccc43)-c3cc4c(cc32)sc2cc(N(c3ccc(C(C)(C)C)cc3)c3ccc(C(C)(C)C)cc3)ccc24)cc1] 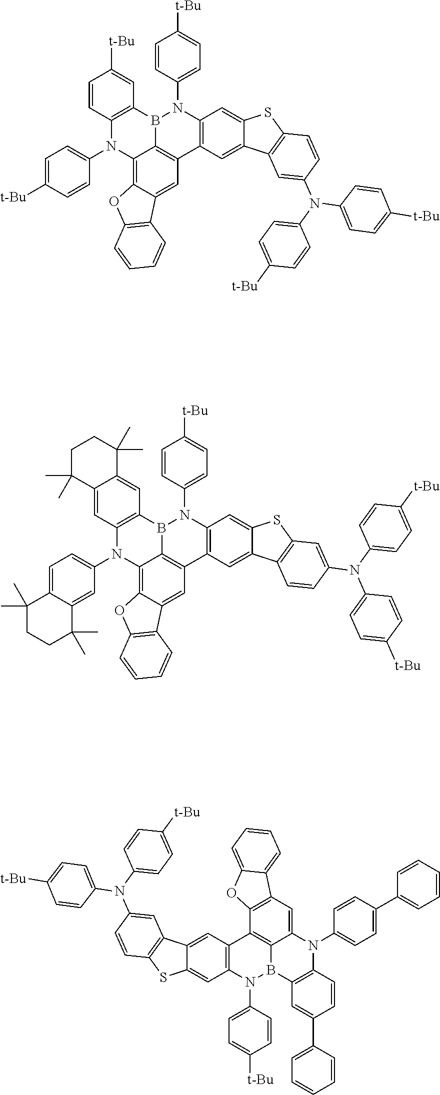 [SMILES: CC(C)(C)c1ccc(N2B3c4cc(C(C)(C)C)ccc4N(c4ccc(C(C)(C)C)cc4)c4c3c(cc3c4oc4ccccc43)-c3cc4c(cc32)sc2ccc(N(c3ccc(C(C)(C)C)cc3)c3ccc(C(C)(C)C)cc3)cc24)cc1 ; CC(C)(C)c1ccc(N2B3c4cc5c(cc4N(c4ccc6c(c4)C(C)(C)CCC6(C)C)c4c3c(cc3c4oc4ccccc43)-c3cc4c(cc32)sc2cc(N(c3ccc(C(C)(C)C)cc3)c3ccc(C(C)(C)C)cc3)ccc24)C(C)(C)CCC5(C)C)cc1 ; CC(C)(C)c1ccc(N2B3c4cc(-c5ccccc5)ccc4N(c4ccc(-c5ccccc5)cc4)c4cc5c(oc6ccccc65)c(c43)-c3cc4c(cc32)sc2ccc(N(c3ccc(C(C)(C)C)cc3)c3ccc(C(C)(C)C)cc3)cc24)cc1] 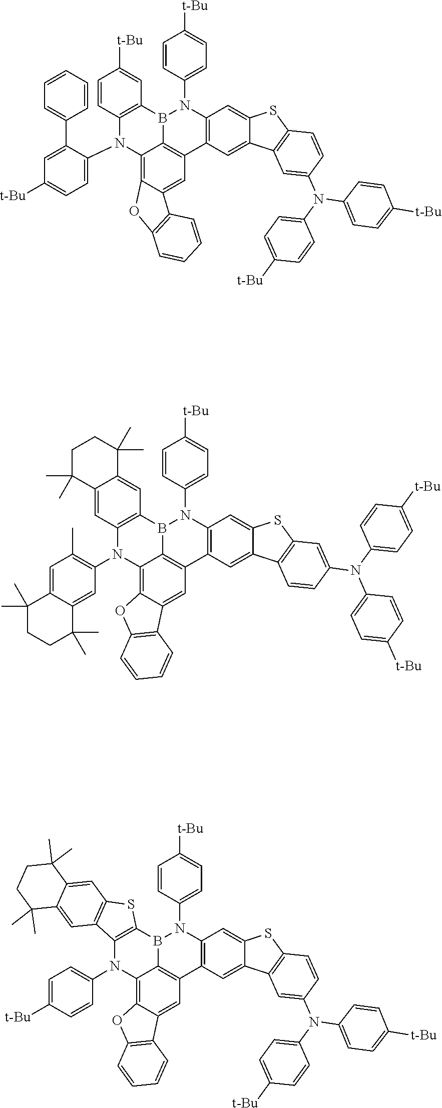 [SMILES: CC(C)(C)c1ccc(N2B3c4cc(C(C)(C)C)ccc4N(c4ccc(C(C)(C)C)cc4-c4ccccc4)c4c3c(cc3c4oc4ccccc43)-c3cc4c(cc32)sc2ccc(N(c3ccc(C(C)(C)C)cc3)c3ccc(C(C)(C)C)cc3)cc24)cc1 ; Cc1cc2c(cc1N1c3cc4c(cc3B3c5c(cc6c(oc7ccccc76)c51)-c1cc5c(cc1N3c1ccc(C(C)(C)C)cc1)sc1cc(N(c3ccc(C(C)(C)C)cc3)c3ccc(C(C)(C)C)cc3)ccc15)C(C)(C)CCC4(C)C)C(C)(C)CCC2(C)C ; CC(C)(C)c1ccc(N2B3c4sc5cc6c(cc5c4N(c4ccc(C(C)(C)C)cc4)c4c3c(cc3c4oc4ccccc43)-c3cc4c(cc32)sc2ccc(N(c3ccc(C(C)(C)C)cc3)c3ccc(C(C)(C)C)cc3)cc24)C(C)(C)CCC6(C)C)cc1] 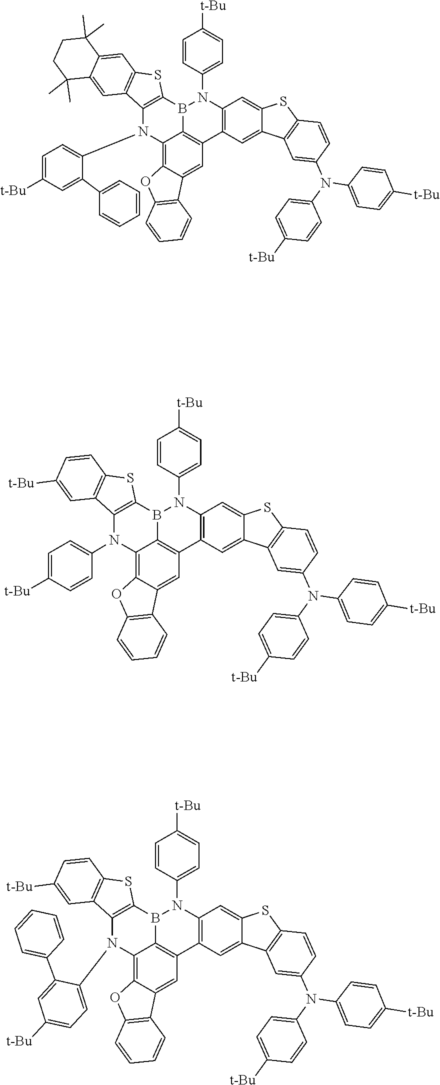 [SMILES: CC(C)(C)c1ccc(N2B3c4sc5cc6c(cc5c4N(c4ccc(C(C)(C)C)cc4-c4ccccc4)c4c3c(cc3c4oc4ccccc43)-c3cc4c(cc32)sc2ccc(N(c3ccc(C(C)(C)C)cc3)c3ccc(C(C)(C)C)cc3)cc24)C(C)(C)CCC6(C)C)cc1 ; CC(C)(C)c1ccc(N2B3c4sc5ccc(C(C)(C)C)cc5c4N(c4ccc(C(C)(C)C)cc4)c4c3c(cc3c4oc4ccccc43)-c3cc4c(cc32)sc2ccc(N(c3ccc(C(C)(C)C)cc3)c3ccc(C(C)(C)C)cc3)cc24)cc1 ; CC(C)(C)c1ccc(N2B3c4sc5ccc(C(C)(C)C)cc5c4N(c4ccc(C(C)(C)C)cc4-c4ccccc4)c4c3c(cc3c4oc4ccccc43)-c3cc4c(cc32)sc2ccc(N(c3ccc(C(C)(C)C)cc3)c3ccc(C(C)(C)C)cc3)cc24)cc1] 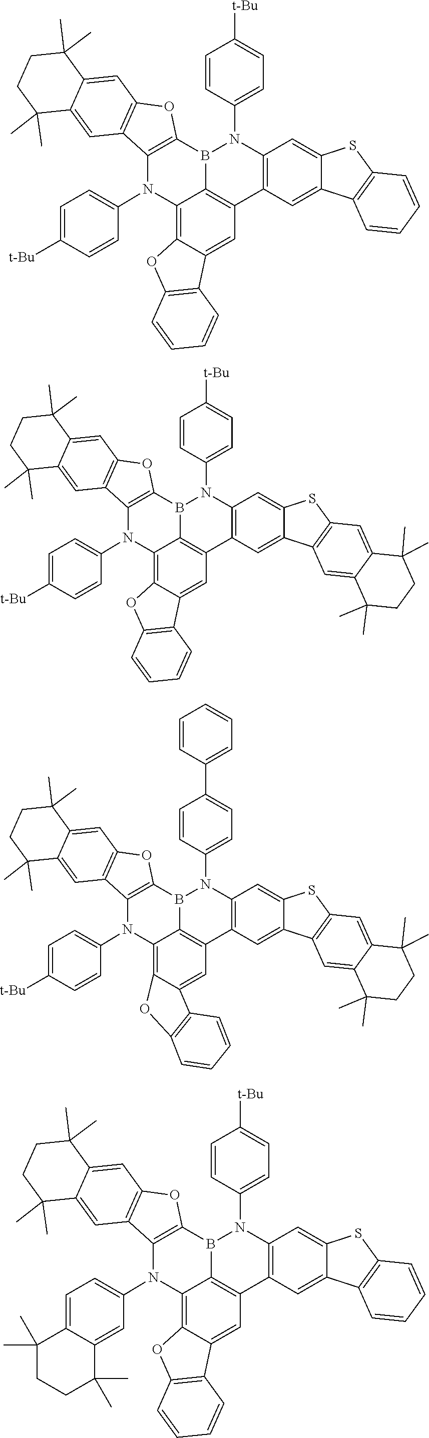 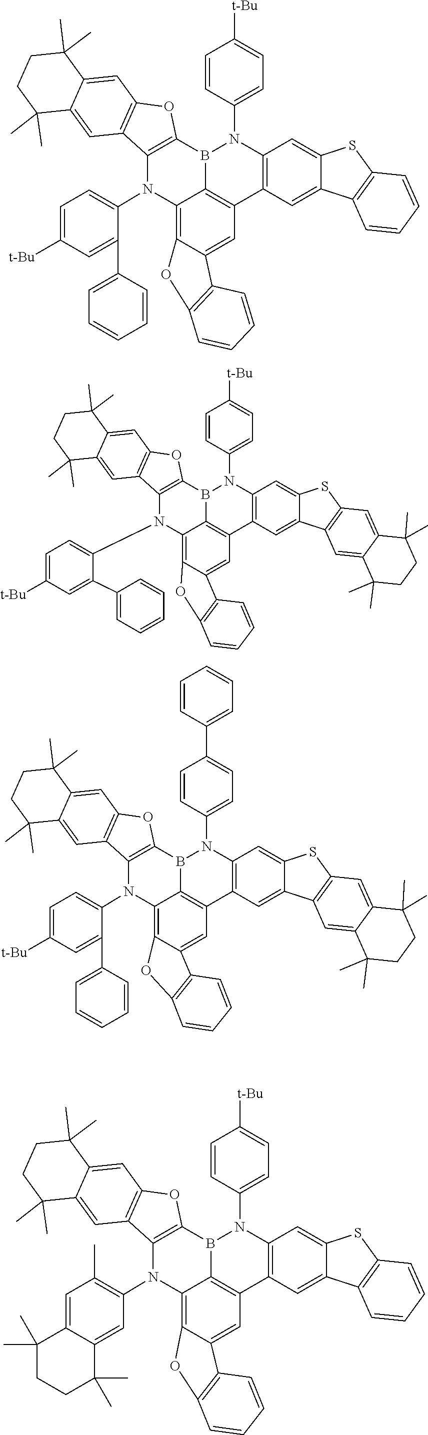 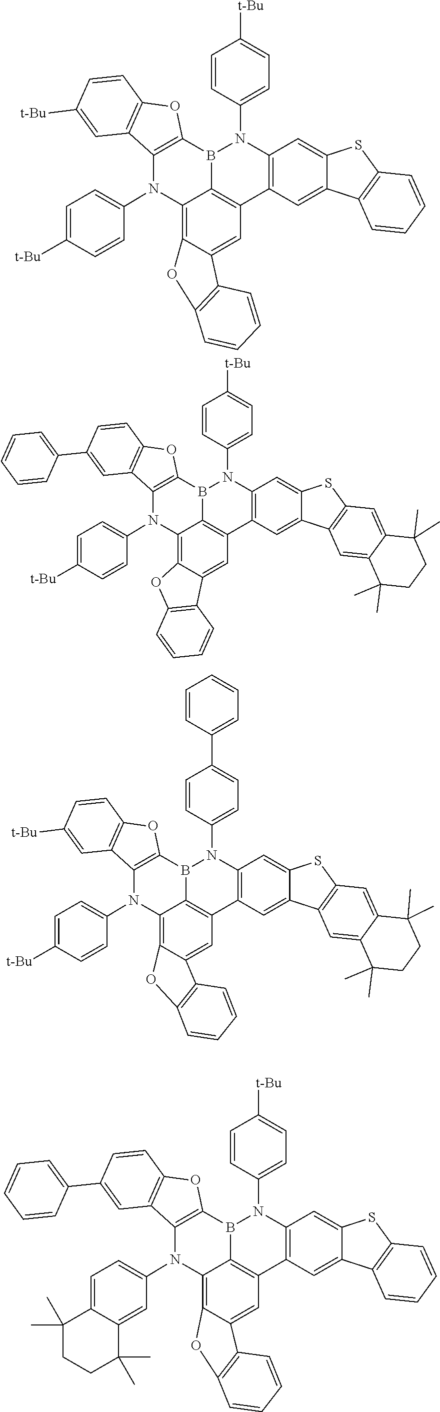 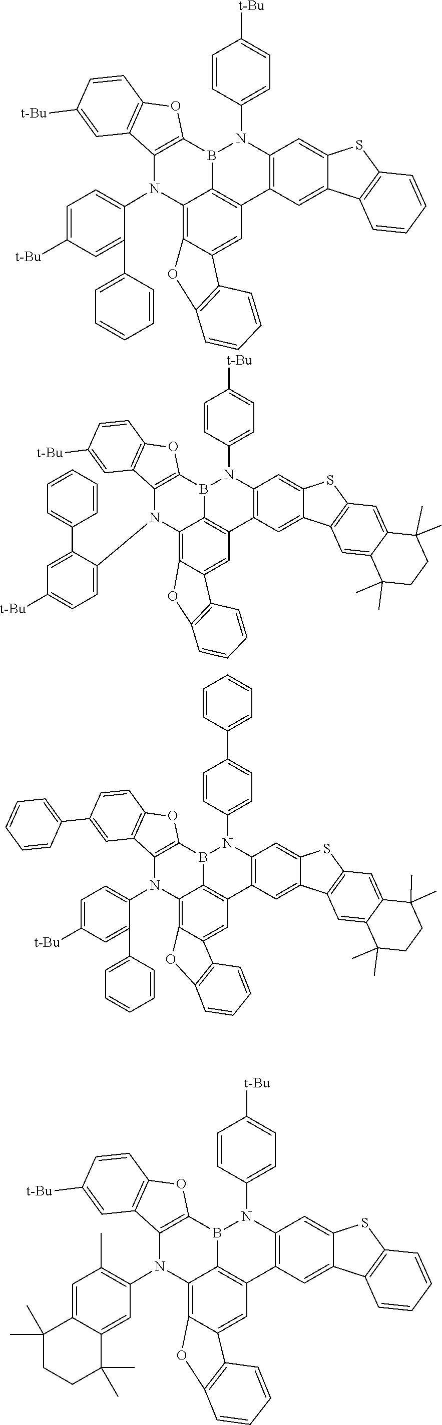 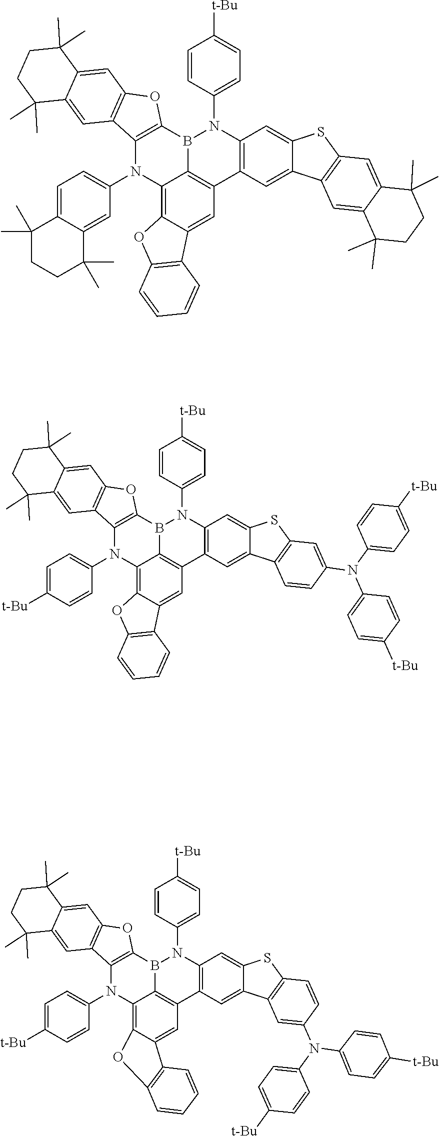 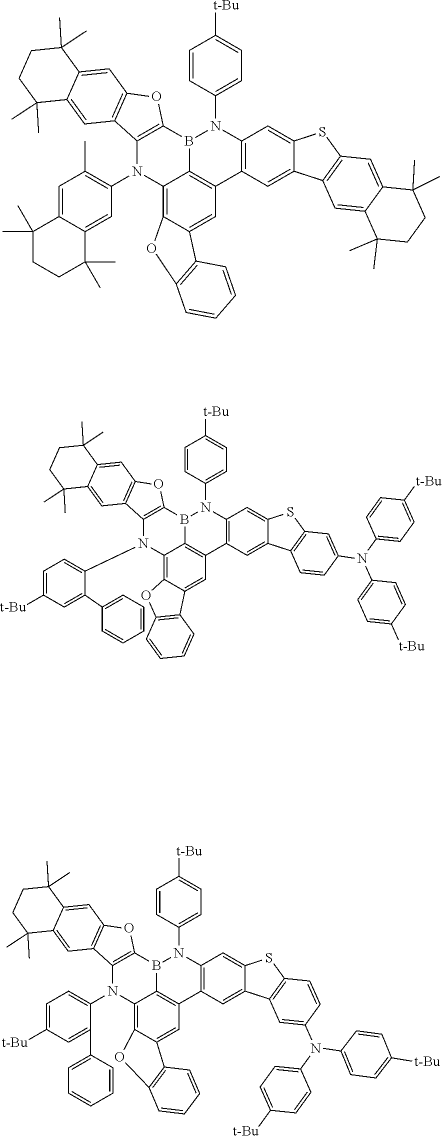 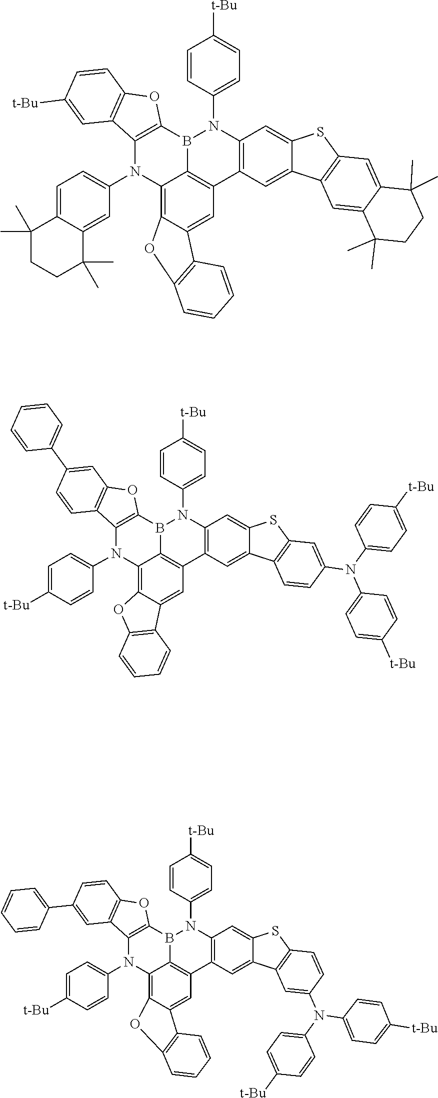 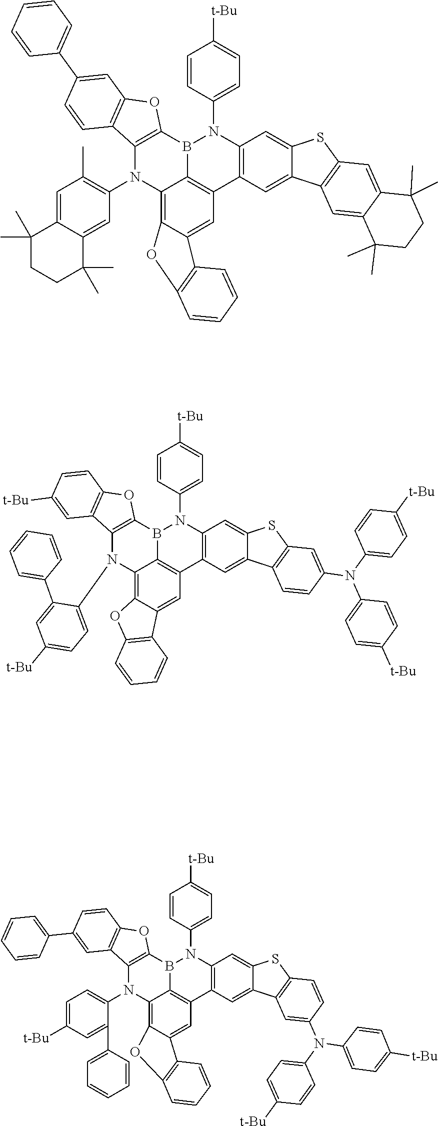 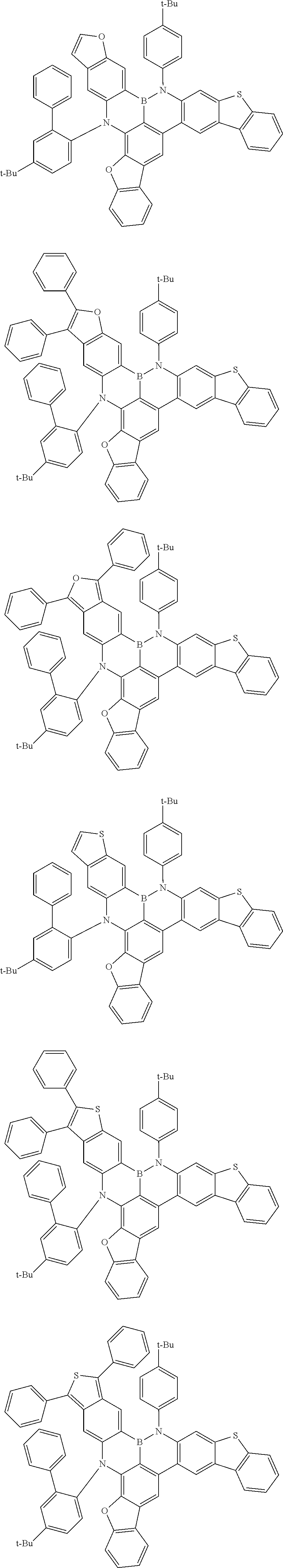 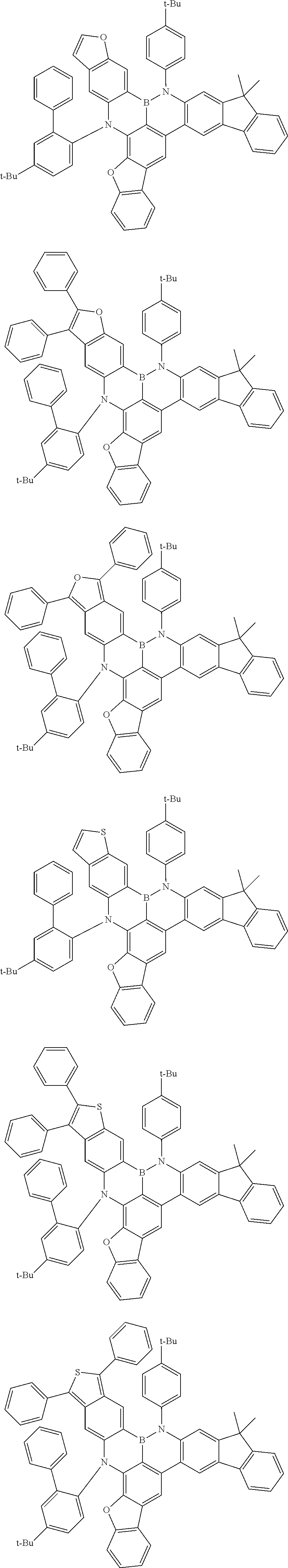 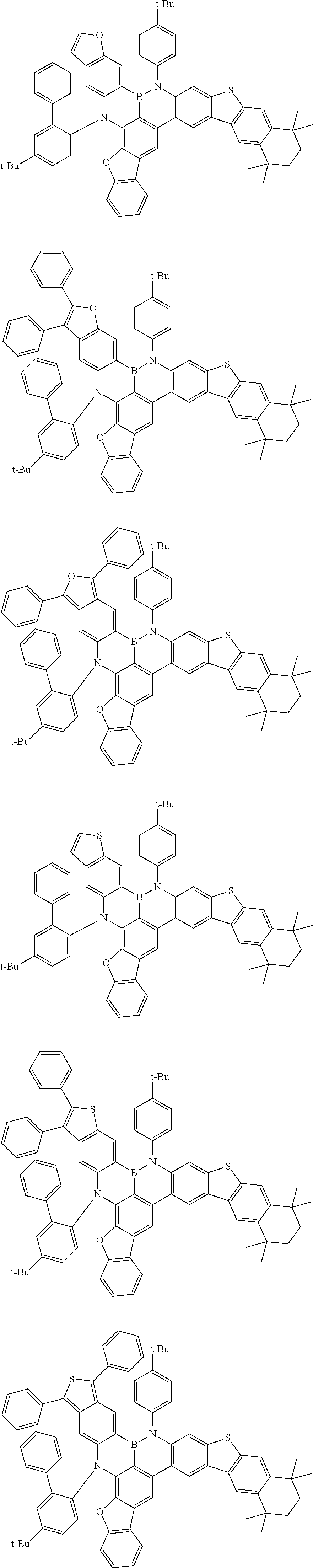 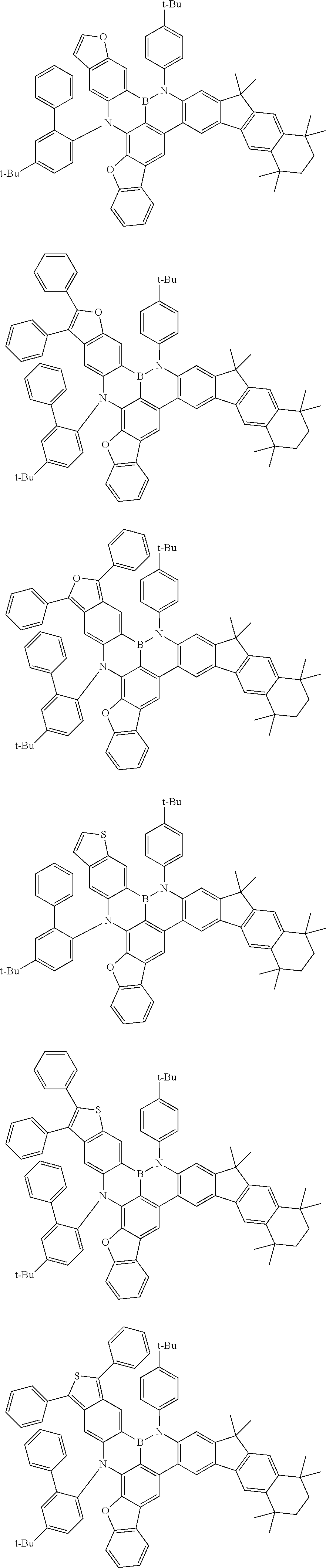 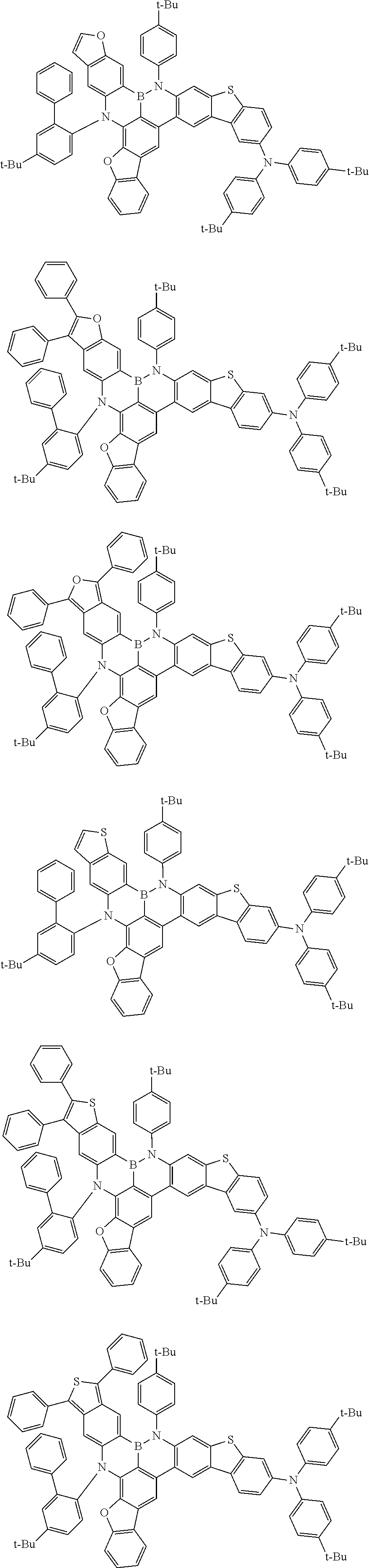 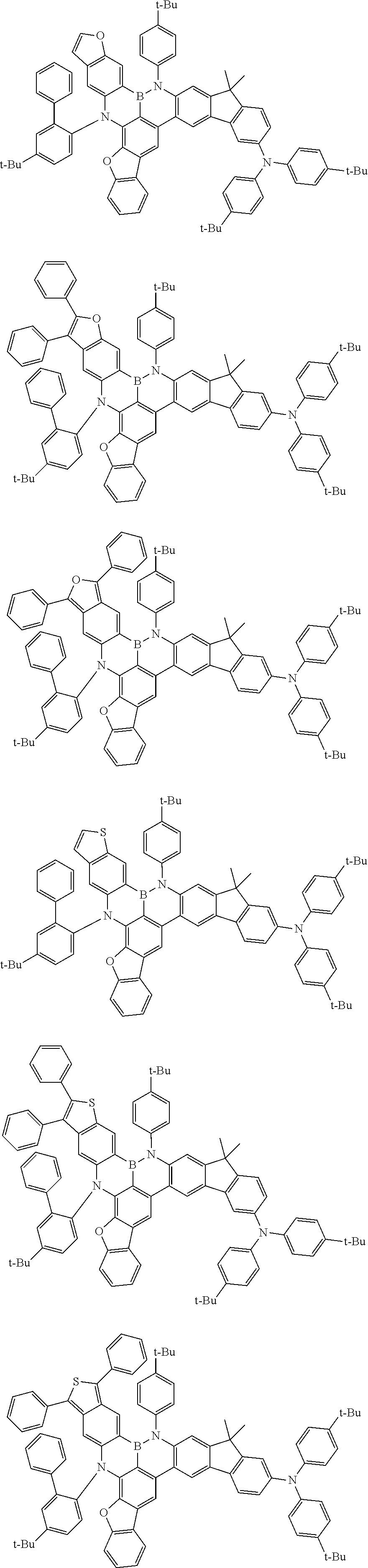 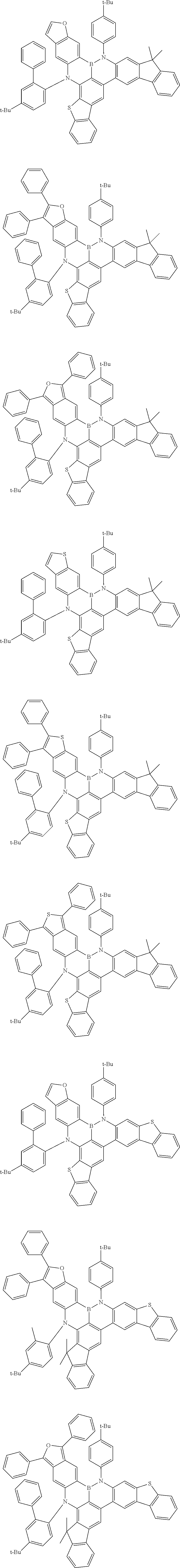 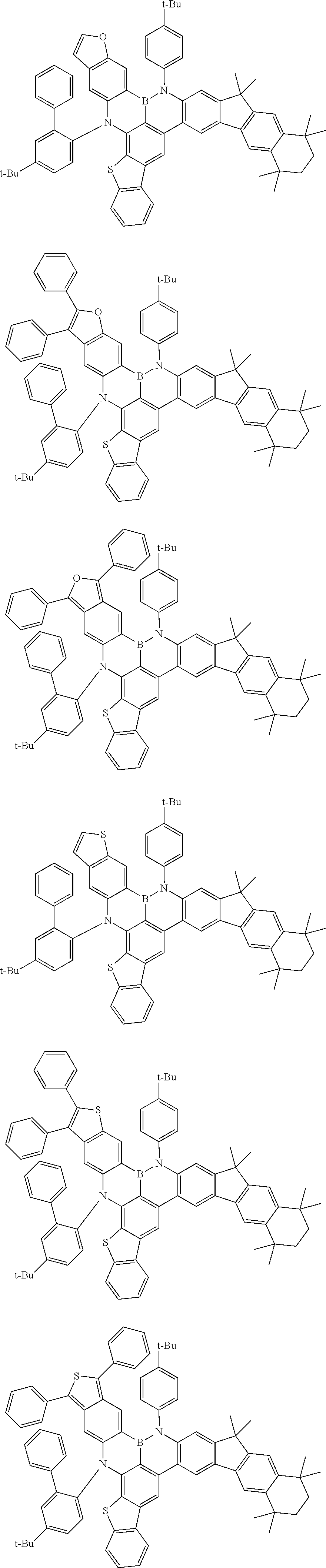 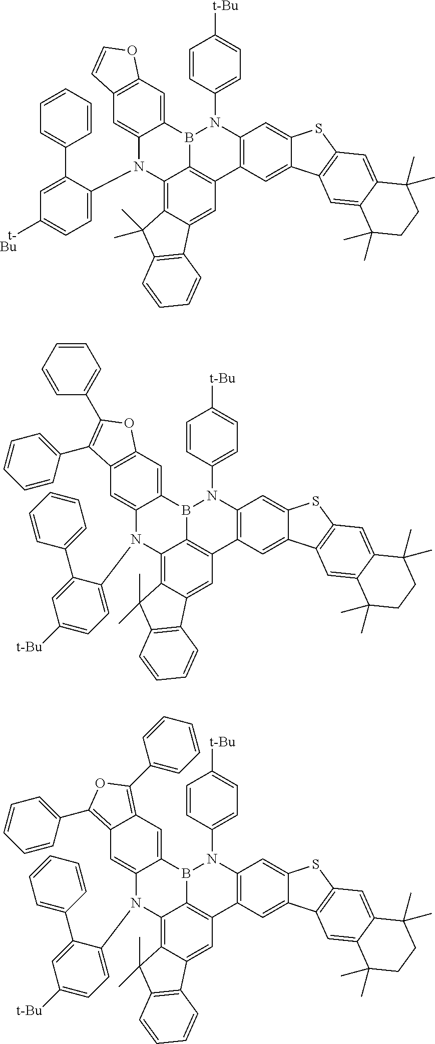 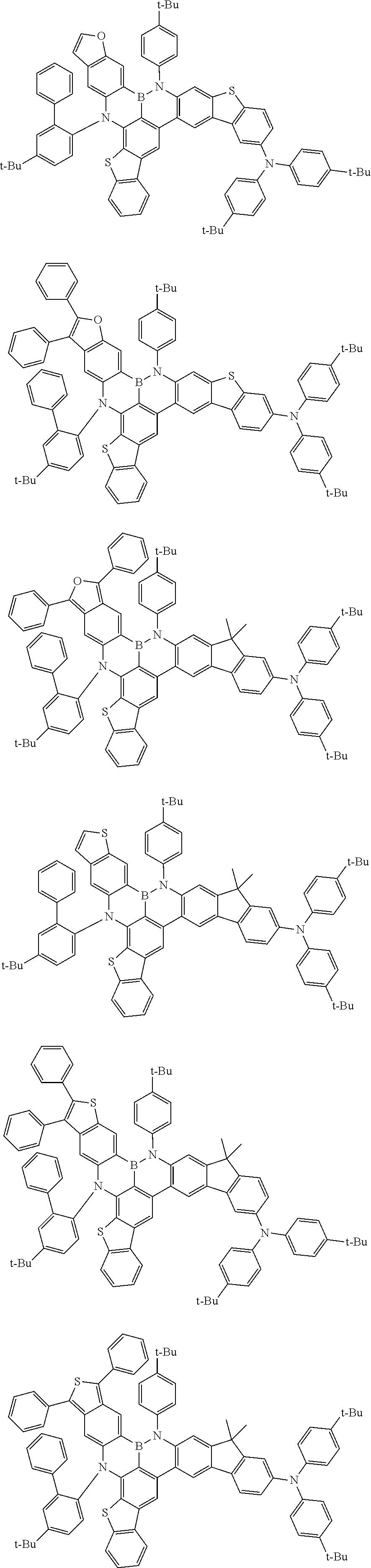 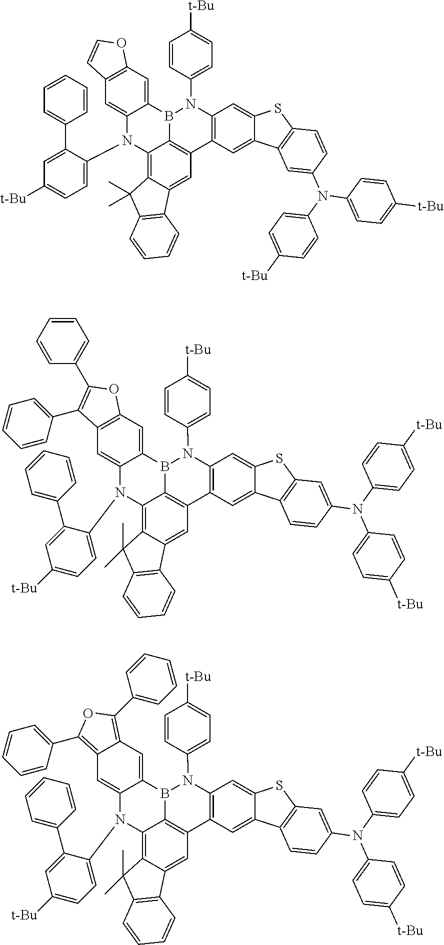 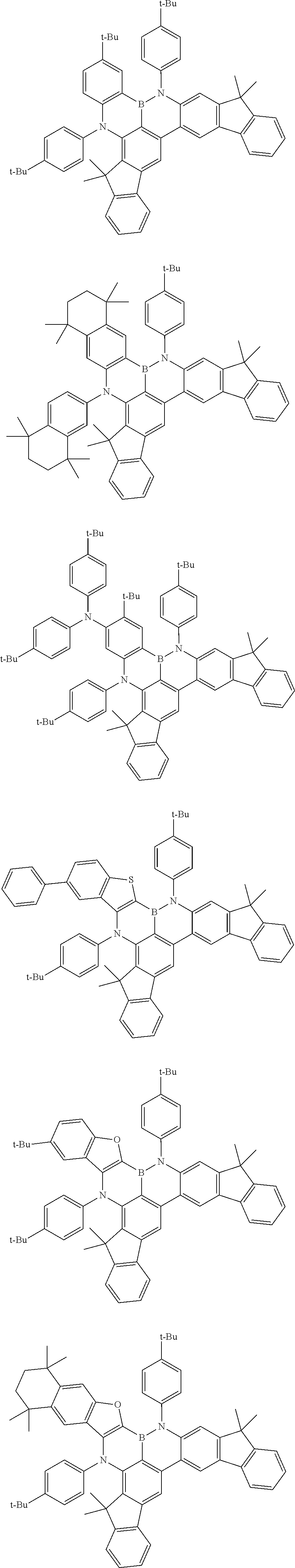 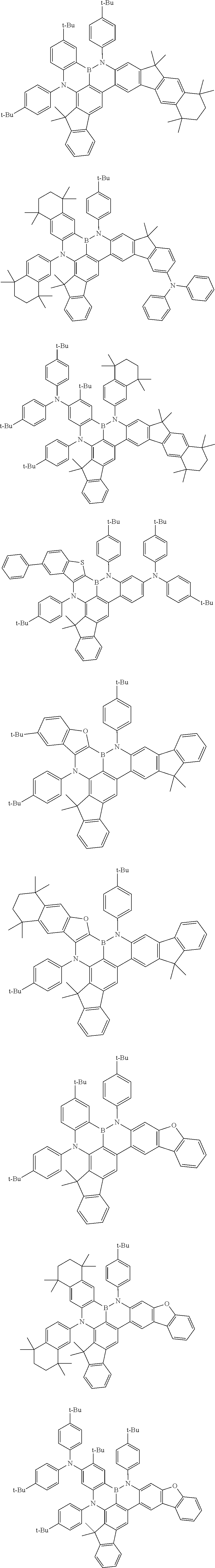 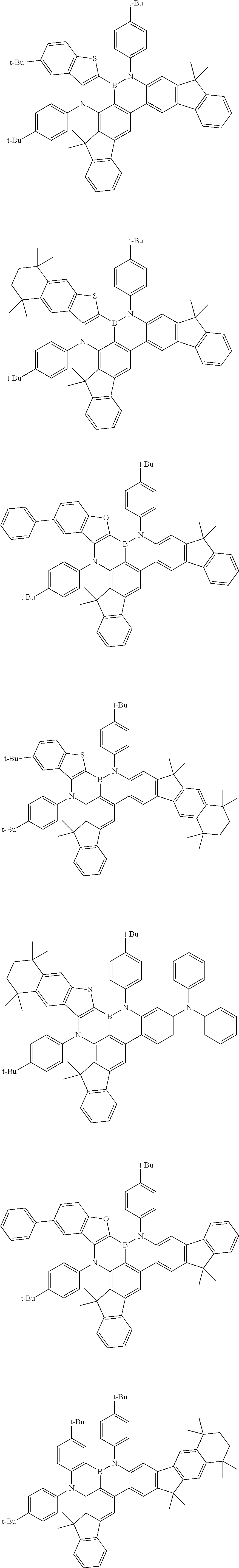 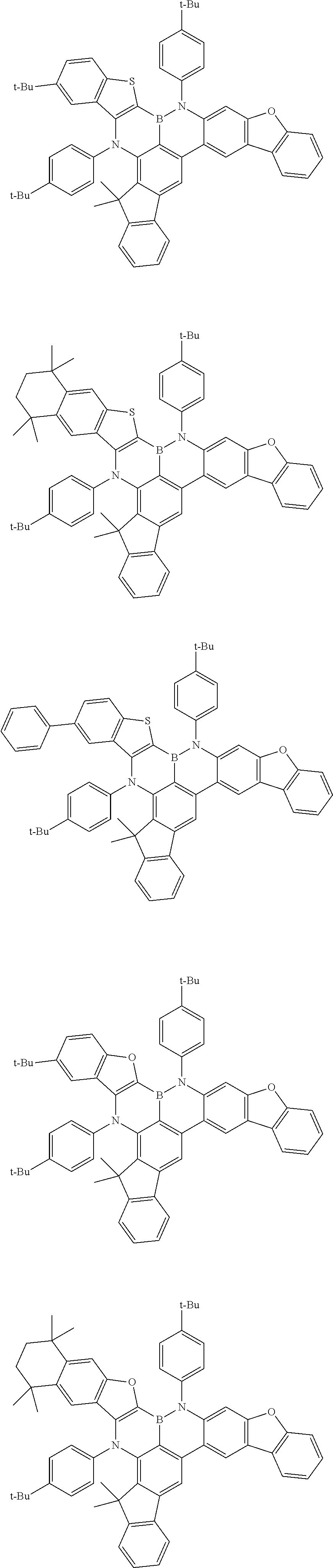 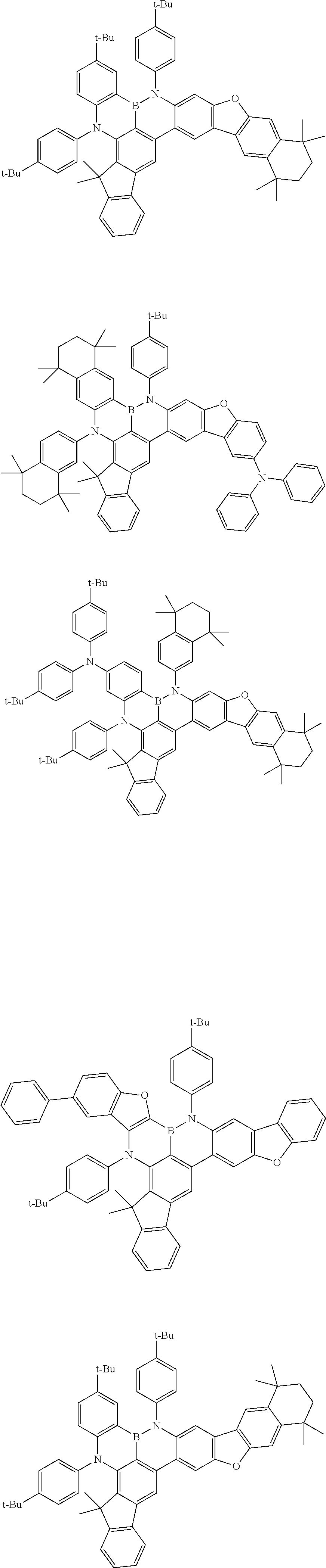 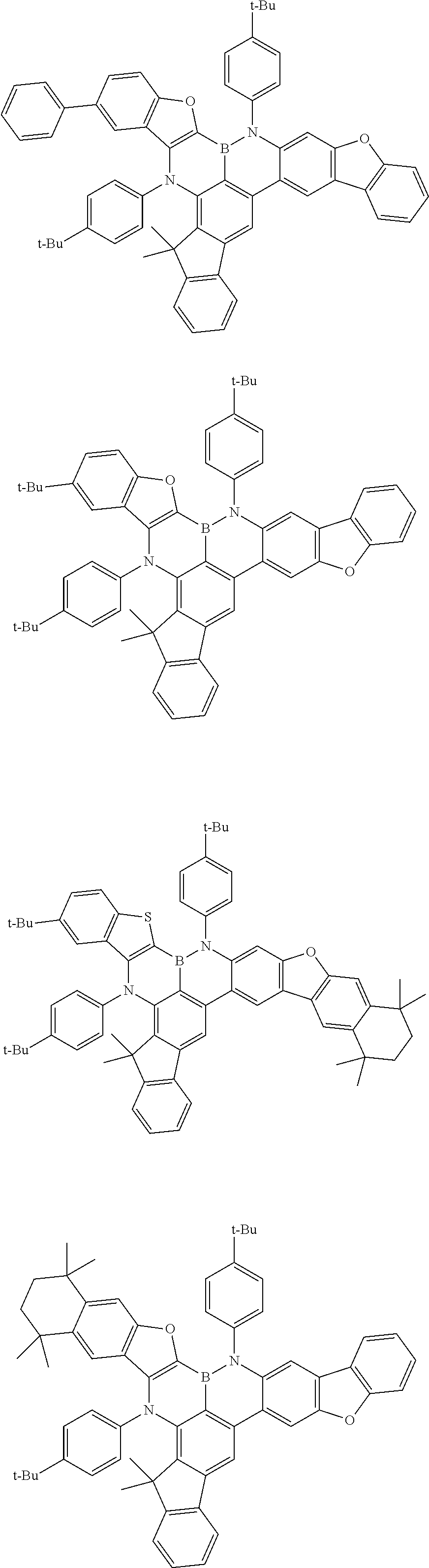 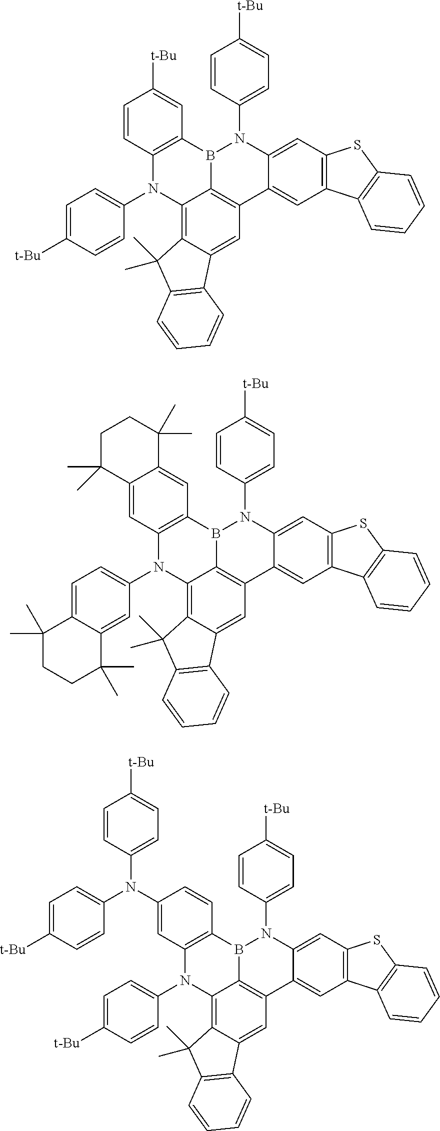 [SMILES: CC(C)(C)c1ccc(N2B3c4cc(C(C)(C)C)ccc4N(c4ccc(C(C)(C)C)cc4)c4c3c(cc3c4C(C)(C)c4ccccc4-3)-c3cc4c(cc32)sc2ccccc24)cc1 ; CC(C)(C)c1ccc(N2B3c4cc5c(cc4N(c4ccc6c(c4)C(C)(C)CCC6(C)C)c4c3c(cc3c4C(C)(C)c4ccccc4-3)-c3cc4c(cc32)sc2ccccc24)C(C)(C)CCC5(C)C)cc1 ; CC(C)(C)c1ccc(N2B3c4ccc(N(c5ccc(C(C)(C)C)cc5)c5ccc(C(C)(C)C)cc5)cc4N(c4ccc(C(C)(C)C)cc4)c4c3c(cc3c4C(C)(C)c4ccccc4-3)-c3cc4c(cc32)sc2ccccc24)cc1] 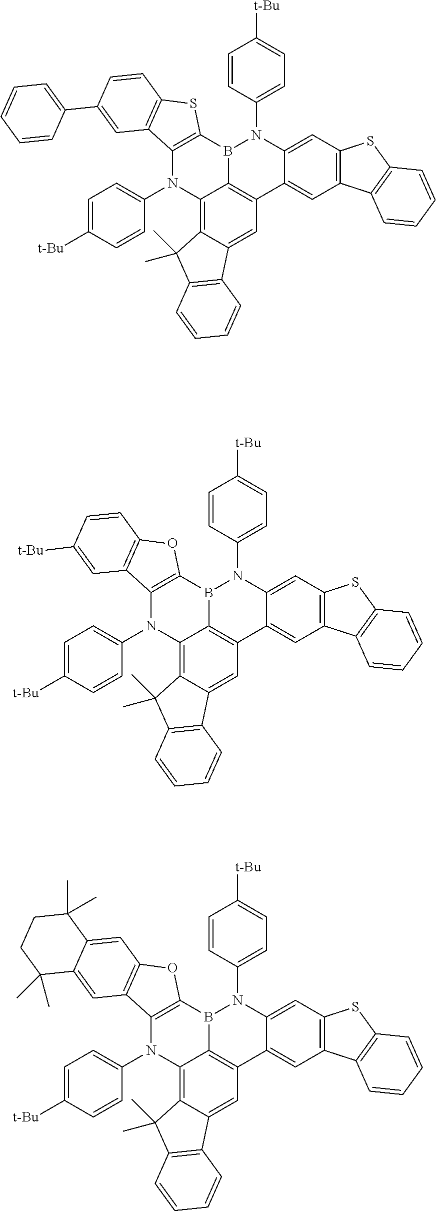 [SMILES: CC(C)(C)c1ccc(N2B3c4sc5ccc(-c6ccccc6)cc5c4N(c4ccc(C(C)(C)C)cc4)c4c3c(cc3c4C(C)(C)c4ccccc4-3)-c3cc4c(cc32)sc2ccccc24)cc1 ; CC(C)(C)c1ccc(N2B3c4oc5ccc(C(C)(C)C)cc5c4N(c4ccc(C(C)(C)C)cc4)c4c3c(cc3c4C(C)(C)c4ccccc4-3)-c3cc4c(cc32)sc2ccccc24)cc1 ; CC(C)(C)c1ccc(N2B3c4oc5cc6c(cc5c4N(c4ccc(C(C)(C)C)cc4)c4c3c(cc3c4C(C)(C)c4ccccc4-3)-c3cc4c(cc32)sc2ccccc24)C(C)(C)CCC6(C)C)cc1] 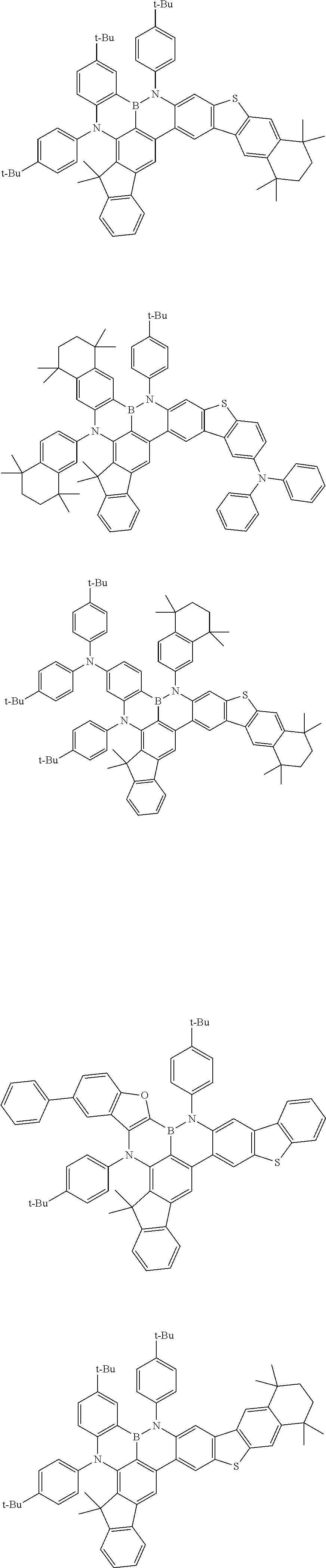 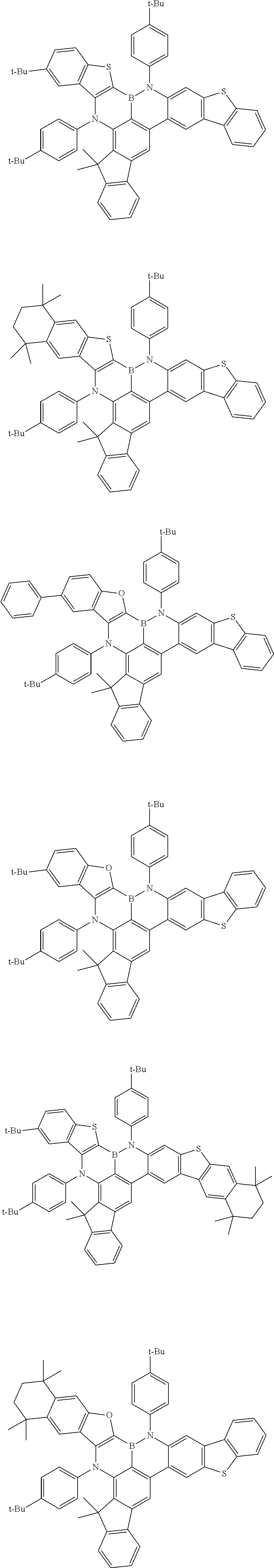 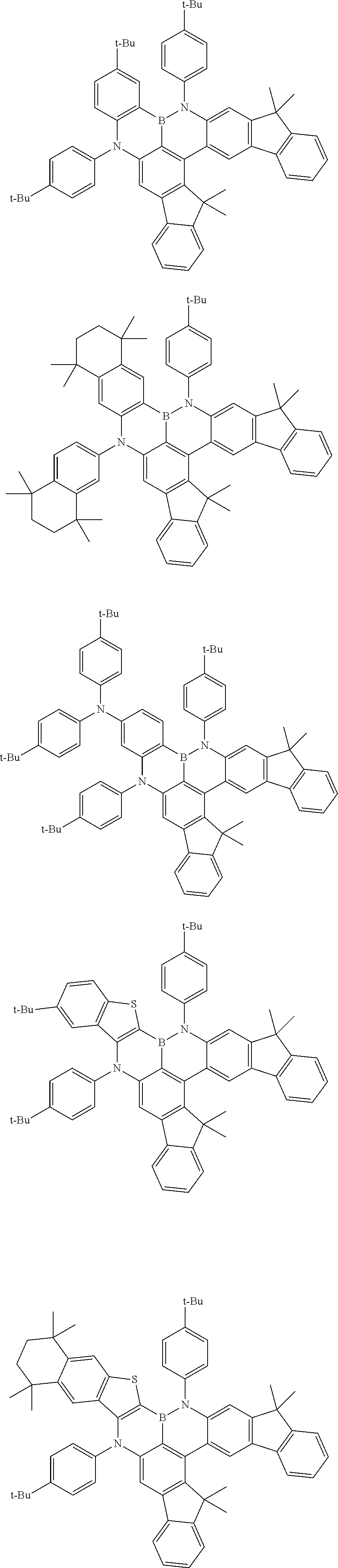 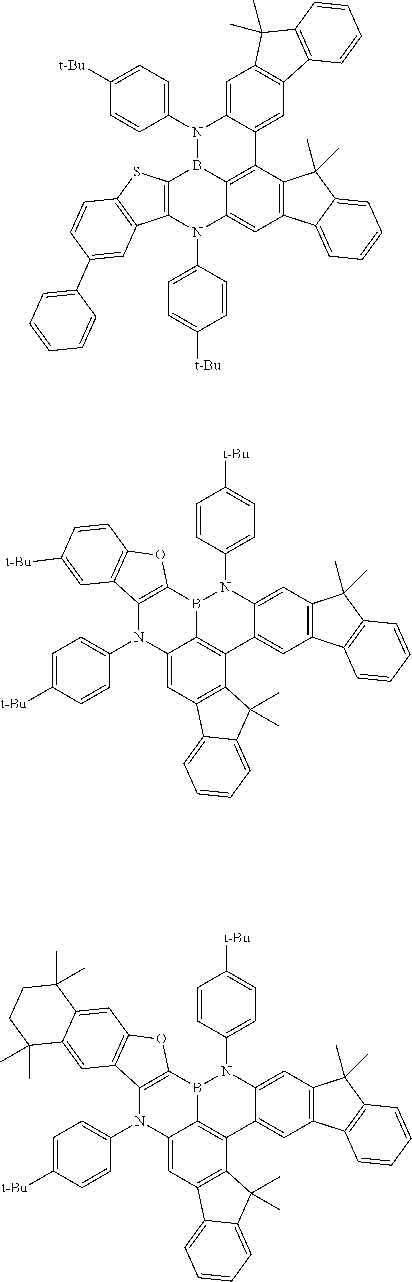 [SMILES: CC(C)(C)c1ccc(N2B3c4sc5ccc(-c6ccccc6)cc5c4N(c4ccc(C(C)(C)C)cc4)c4cc5c(c(c43)-c3cc4c(cc32)C(C)(C)c2ccccc2-4)C(C)(C)c2ccccc2-5)cc1 ; CC(C)(C)c1ccc(N2B3c4oc5ccc(C(C)(C)C)cc5c4N(c4ccc(C(C)(C)C)cc4)c4cc5c(c(c43)-c3cc4c(cc32)C(C)(C)c2ccccc2-4)C(C)(C)c2ccccc2-5)cc1 ; CC(C)(C)c1ccc(N2B3c4oc5cc6c(cc5c4N(c4ccc(C(C)(C)C)cc4)c4cc5c(c(c43)-c3cc4c(cc32)C(C)(C)c2ccccc2-4)C(C)(C)c2ccccc2-5)C(C)(C)CCC6(C)C)cc1] 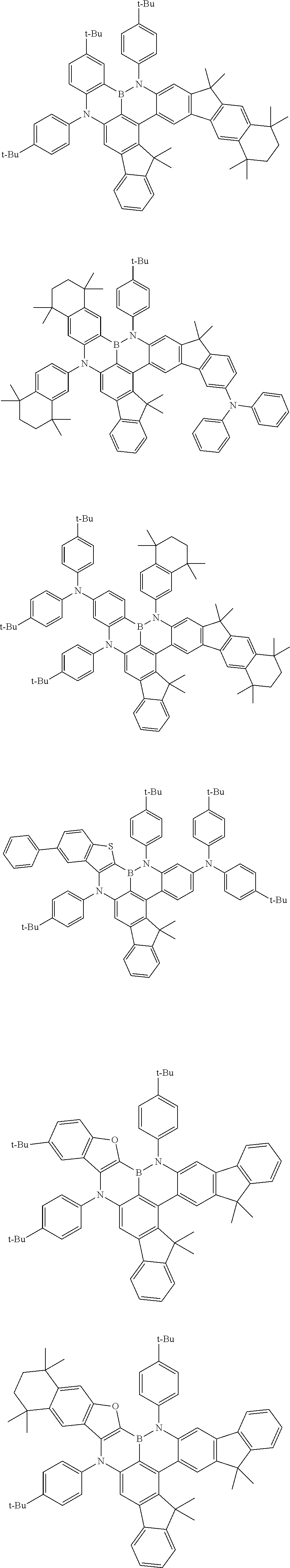 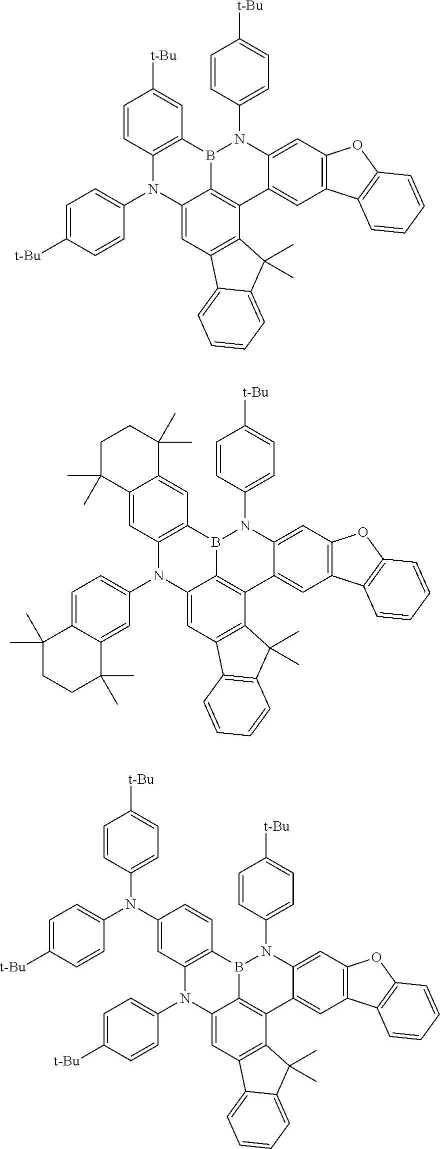 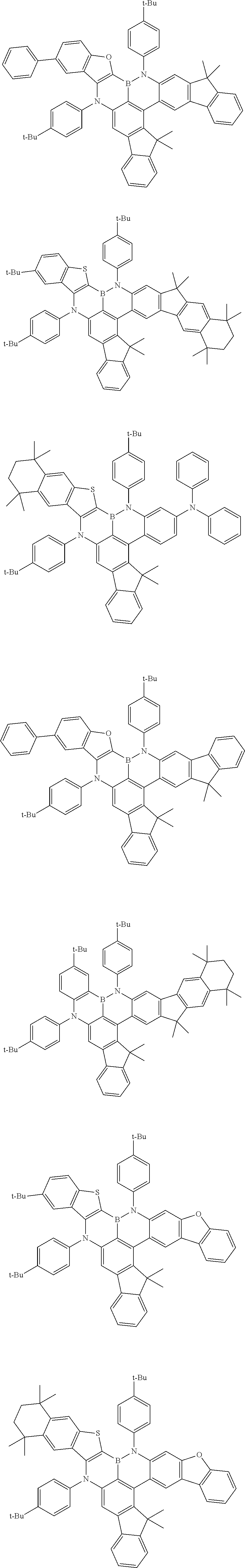 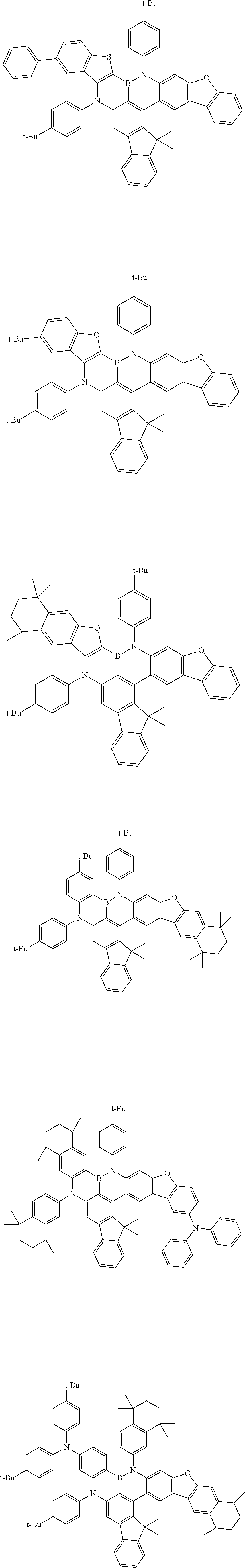 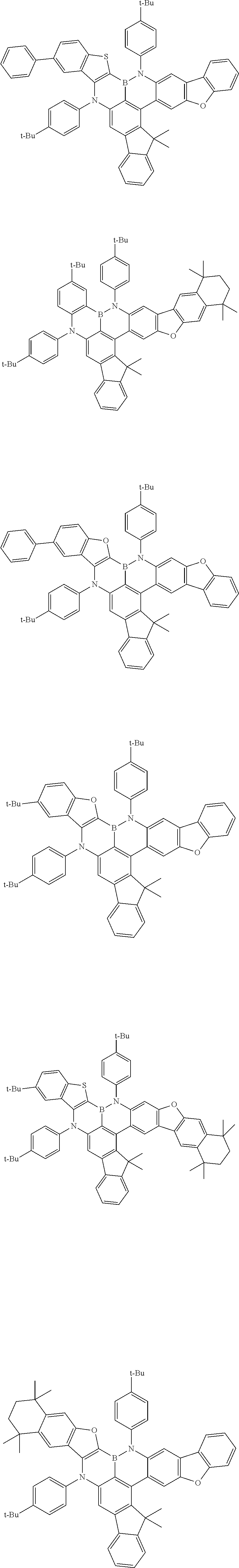 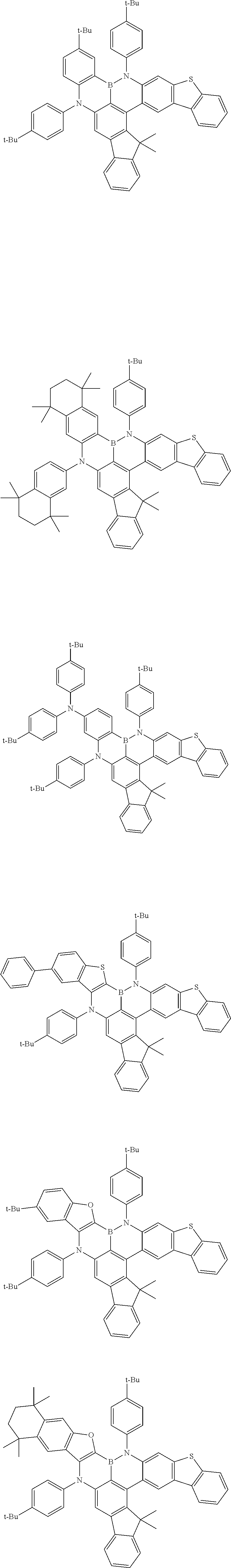 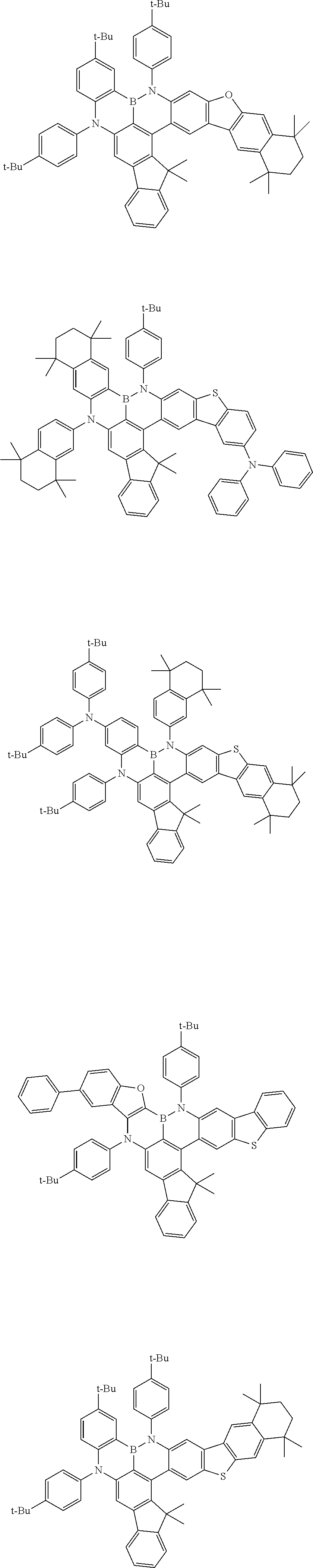 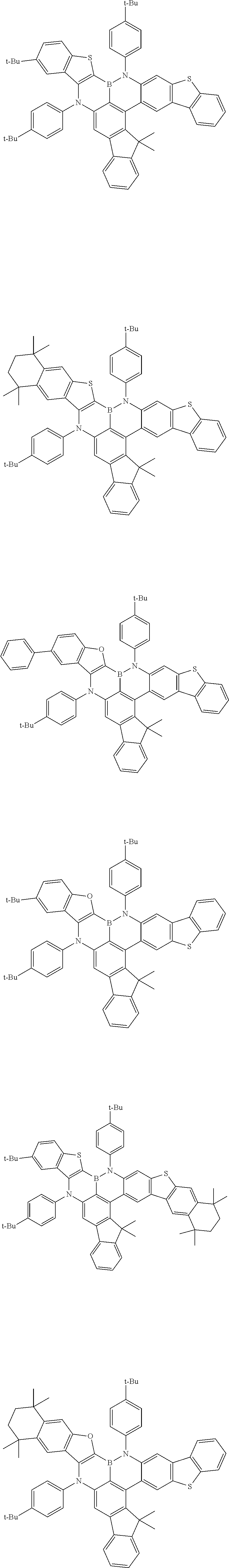
wherein t-Bu is a tert-butyl group.

10. An organic light emitting device comprising:
a first electrode;
a second electrode; and
an organic material layer comprising one or more layers between the first electrode and the second electrode,
wherein one or more layers of the organic material layer include the compound of claim 1.

11. The organic light emitting device of claim 10, wherein the organic material layer includes a light emitting layer, and the light emitting layer includes the compound.

12. The organic light emitting device of claim 10, wherein the organic material layer includes a light emitting layer, the light emitting layer includes a dopant material, and the dopant material includes the compound.

13. The organic light emitting device of claim 10, wherein the organic material layer includes a light emitting layer, and the light emitting layer further includes a compound represented by the following Chemical Formula H: 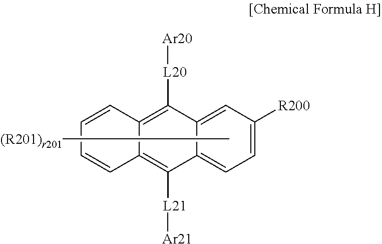
wherein in Chemical Formula H,
L20 and L21 are the same as or different from each other, and each independently a direct bond; a substituted or unsubstituted arylene group; or a substituted or unsubstituted heterocyclic group,
Ar20 and Ar21 are the same as or different from each other, and each independently hydrogen; deuterium; a substituted or unsubstituted aryl group; or a substituted or unsubstituted heterocyclic group,
R200 and R201 are the same as or different from each other, and each independently hydrogen; deuterium; a halogen group; a substituted or unsubstituted alkyl group; a substituted or unsubstituted cycloalkyl group; a substituted or unsubstituted aryl group; or a substituted or unsubstituted heterocyclic group, and
r201 is an integer of 1 to 7, and when r201 is 2 or greater, the two or more R201s are the same as or different from each other.

14. The organic light emitting device of claim 12, wherein the light emitting layer further includes a host compound, and in the host compound, at least one hydrogen is substituted with deuterium.

15. The organic light emitting device of claim 12, wherein the light emitting layer further includes one or more of dopants and hosts.

16. The organic light emitting device of claim 12, wherein the light emitting layer further includes one or more hosts.

17. The organic light emitting device of claim 12, wherein the light emitting layer further includes a mixed host of two or more hosts.
